(19) United States
(12) Patent Application Publication
(10) Pub. No.: US 2023/0165095 A1
(43) Pub. Date: May 25, 2023

(54) LIGHT-EMITTING DEVICE AND ELECTRONIC APPARATUS INCLUDING THE SAME

(71) Applicant: Samsung Electronics Co., Ltd., Suwon-si (KR)

(72) Inventors: Sunghun Lee, Hwaseong-si (KR); Seungyeon Kwak, Suwon-si (KR); Myungsun Sim, Suwon-si (KR)

(21) Appl. No.: 17/932,421

(22) Filed: Sep. 15, 2022

(30) Foreign Application Priority Data
Sep. 16, 2021 (KR) 10-2021-0124268

(51) Int. Cl. H01L 27/32; H01L 51/00

(52) U.S. Cl. CPC H01L 27/3209; H01L 27/322; H01L 51/0087; H01L 51/0085

(57) ABSTRACT

A light-emitting device includes: an OLED substrate including a structure wherein at least one blue emission unit and at least one green emission unit are stacked, and wherein the OLED substrate emits blue light and green light; and a color control unit located in a path of light emitted from the OLED substrate, wherein at least one green emission unit includes a first compound and a second compound, the first compound emits first light having a first spectrum, and λP(1) is a first emission peak wavelength, the second compound emits second light having a second spectrum, and λP(2) is a second emission peak wavelength, an absolute value of the difference between λP(1) and λP(2) is from 0 nanometer to about 30 nanometer, and λP(1) and λP(2) are each independently from about 500 nanometer to about 570 nanometer.

### CROSS-REFERENCE TO RELATED APPLICATION

This application is based on and claims priority to Korean Patent Application No. 10-2021-0124268, filed on Sep. 16, 2021, in the Korean Intellectual Property Office, and all benefits under 35 U.S.C. § 119, the content of which is incorporated by reference herein in its entirety.

### BACKGROUND

### 1. Field

The present disclosure relates to light-emitting devices and electronic apparatuses including the same.

### 2. Description of the Related Art

From among light-emitting devices, organic light-emitting devices (OLEDs) are self-emission devices, which have improved characteristics in terms of viewing angles, response time, luminance, driving voltage, and response speed, and produce full-color images.

In an example, an organic light-emitting device includes an anode, a cathode, and an organic layer located between the anode and the cathode, wherein the organic layer includes an emission layer. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transition from an excited state to a ground state to thereby generate light.

Meanwhile, a light-emitting device including a plurality of color conversion elements (for example, quantum dot color conversion elements) uses a blue-organic light-emitting device substrate or a white-organic light-emitting device substrate as a light source.

### SUMMARY

Provided are light-emitting devices having high luminescence efficiency and long lifespans, and electronic apparatuses including the same.

Additional aspects will be set forth in part in the description, which follows and, in part, will be apparent from the description, or may be learned by practice of the presented embodiments of the disclosure.

According to an aspect, a light-emitting device includes:

an organic light-emitting device (OLED) substrate including a structure in which at least one blue emission unit and at least one green emission unit are stacked, wherein the OLED substrate emits blue light and green light; and

a color control unit located in the path of light emitted from the OLED substrate, wherein the color control unit controls a color of the light emitted from the OLED substrate,

wherein the at least one green emission unit includes a first compound and a second compound,

the first compound and the second compound may be different from each other,

the first compound emits first light having a first spectrum, and λP(1) is a first emission peak wavelength (nm) of the first spectrum, as evaluated from a first photoluminescence spectrum measured from a first film including the first compound,

the second compound may emit second light having a second spectrum, and λP(2) is a second emission peak wavelength (nm) of the second spectrum, as evaluated from a second photoluminescence spectrum measured from a second film including the second compound,

an absolute value of the difference between λP(1) and λP(2) is from about 0 nanometer (nm) to about 30 nm, and

λP(1) and λP(2) are each independently from about 500 nm to about 570 nm.

Both the first compound and the second compound may emit a green light.

According to another aspect, a light-emitting device includes:

an organic light-emitting device (OLED) substrate including a structure in which at least one blue emission unit and at least one green emission unit are stacked, wherein the OLED substrate emits blue light and green light; and

a color control unit located in the path of light emitted from the OLED substrate, wherein the color control unit controls a color of the light emitted from the OLED substrate,

wherein the at least one green emission unit includes a first compound and a second compound,

the first compound and the second compound may be different from each other,

the first compound and the second compound may emit a green light,

an absolute value of the difference between λP(1) and λP(2) is from about 0 nanometer (nm) to about 30 nm, and

λP(1) and λP(2) are each independently from about 500 nm to about 570 nm.

According to another aspect, provided is an organic light-emitting device (OLED) substrate including a structure in which at least one blue emission unit and at least one green emission unit are stacked, wherein the OLED substrate emits blue light and green light,

wherein the at least one green emission unit includes a first compound and a second compound,

the first compound and the second compound may be different from each other,

the first compound emits first light having a first spectrum, and λP(1) is a first emission peak wavelength (nm) of the first spectrum, as evaluated from a first photoluminescence spectrum measured from a first film including the first compound,

the second compound may emit second light having a second spectrum, and λP(2) is a second emission peak wavelength (nm) of the second spectrum, as evaluated from a second photoluminescence spectrum measured from a second film including the second compound,

an absolute value of the difference between λP(1) and λP(2) is from about 0 nanometer (nm) to about 30 nm, and

λP(1) and λP(2) are each independently from about 500 nm to about 570 nm.

Both the first compound and the second compound may emit a green light.

According to another aspect, provided is an organic light-emitting device (OLED) substrate including a structure in which at least one blue emission unit and at least one green emission unit are stacked, wherein the OLED substrate emits blue light and green light,

wherein the at least one green emission unit includes a first compound and a second compound,

the first compound and the second compound may be different from each other,

the first compound and the second compound may emit a green light,

an absolute value of the difference between λP(1) and λP(2) is from about 0 nanometer (nm) to about 30 nm, and

λP(1) and λP(2) are each independently from about 500 nm to about 570 nm.

According to another aspect, an electronic apparatus includes the light-emitting device.

### BRIEF DESCRIPTION OF THE DRAWINGS

The above and other aspects, features, and advantages of one or more exemplary embodiments of the disclosure will be more apparent from the following detailed description taken in conjunction with the accompanying drawings, in which:

FIG. 1 is a cross-sectional view illustrating a light-emitting device according to one or more embodiments;

FIGS. 2 to 29 are cross-sectional views illustrating an organic light-emitting device (OLED) substrate applicable to a light-emitting device according to one or more embodiments;

FIG. 30 is a cross-sectional view illustrating an OLED substrate applicable to a light-emitting device according to one or more embodiments;

FIG. 31 is a cross-sectional view illustrating an OLED substrate applicable to a light-emitting device according to one or more embodiments;

FIGS. 32 to 39 are cross-sectional views illustrating a light-emitting device according to one or more embodiments;

FIG. 40 is a graph of photoluminescence quantum yield (PLQY, %) versus wavelength (nanometer, nm) of a green-quantum dot (QD) (i.e., green light emitting quantum dot)-containing color conversion element and a red-QD (i.e., red light emitting quantum dot)-containing color conversion element which are applicable to a light-emitting device according to one or more embodiments;

FIG. 41 is a graph of transmittance (%) versus wavelength (nm) of a green-QD-containing color conversion element and a red-QD-containing color conversion element which are applicable to a light-emitting device according to one or more embodiments;

FIG. 42 is a graph of transmittance (%) versus wavelength (nm) of an absorption-type color filter applicable to a light-emitting device according to one or more embodiments;

FIG. 43 is a graph of spectral radiance (Watts per square meter per Steradian per nanometer, W/m²·sr·nm) versus wavelength (nm) when a light scattering agent is applied to blue light and when no light scattering agent is applied according to one or more embodiments;

FIG. 44 is a graph of intensity (arbitrary units, a.u.) versus wavelength (nm) of the PL spectrum of OLED 2; and

FIG. 45 is a graph of intensity (arbitrary units, a.u.) versus wavelength (nm) of the PL spectrum of Light Emitting Device 1.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Hereinafter, a light-emitting device according to embodiments will be described in further detail with reference to the accompanying drawings. The width and thickness of the layers or regions shown in the accompanying drawings may be exaggerated for clarity of the specification and convenience of description. The same reference numerals denote the same elements throughout the detailed description.

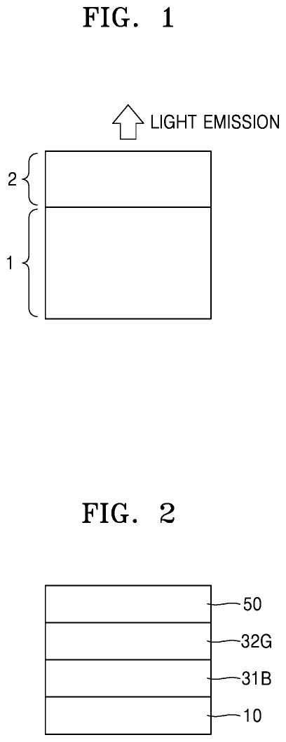

### Description of FIG. 1

FIG. 1 is a cross-sectional view illustrating a light-emitting device according to one or more embodiments.

The light-emitting device of FIG. 1 may include an organic light-emitting device (OLED) substrate 1 and a color control unit 2 located in a path of light emitted from the OLED substrate 1 to control the color of light generated from the OLED substrate 1. The OLED substrate 1 may act as a light source.

The number of emission units included in the OLED substrate 1 may be two or more, or for example, 2 to 20, or 2 to 10. In one or more embodiments, the number of emission units included in the OLED substrate 1 may be 2, 3, 4, or 5.

The OLED substrate 1 includes a structure in which at least one blue emission unit and at least one green emission unit are stacked, for example sequentially stacked. In one or more embodiments, in the OLED substrate 1, the at least one blue emission unit and the at least one green emission unit may be connected in series to each other to form a tandem structure. Accordingly, the OLED substrate 1 may have a tandem structure.

Each of the blue emission units may emit a blue light having an emission peak wavelength of about 440 nanometers (nm) to about 500 nm, or about 450 nm to about 480 nm.

Each of the green emission units may emit a green light having an emission peak wavelength of about 500 nm to about 570 nm, or about 510 nm to about 550 nm.

The number of the blue emission units included in the OLED substrate 1 may be the same as or greater than the number of the green emission units. In one or more embodiments, the ratio of the number of the blue emission units to the number of the green emission units may be 1:1 to 10:1, or 1:1 to 5:1.

In one or more embodiments, the number of the blue emission units may be 1, 2, 3, 4, or 5, and the number of the green emission units may be 1, 2, 3, or 4.

In one or more embodiments, the number of the blue emission units may be 1, 2, or 3, and the number of the green emission units may be 1 or 2.

In one or more embodiments, the number of the blue emission units may be 2 or 3, and the number of the green emission units may be 1 or 2. In one or more embodiments, the number of the blue emission units may 3, and the number of the green emission units may be 1.

The stacking order of the at least one blue emission unit and at least one green emission unit may be variously modified. In one or more embodiments, the at least one blue emission unit and the at least one green emission unit may be alternately stacked. In one or more embodiments, the at least one green emission unit (for example, all green emission units) may be located closer to the color control unit 2 than the at least one blue emission unit (for example, all blue emission units).

From the OLED substrate 1, mixed light including blue light and green light is emitted.

The at least one green emission units of the OLED substrate 1 includes of a first compound and a second compound, for example, the first compound and the second compound may be mixed. The first compound and the second compound are different from each other.

In one or more embodiments, the at least one green emission units of the OLED substrate 1 may include a layer including a mixture of the first compound and the second compound.

The layer including the mixture of the first compound and the second compound may be formed by i) a co-deposition process or ii) a soluble process including providing a first solution and a heat treatment. During the co-deposition process, a deposition target material may include a first compound and a second compound, and the first solution may include the first compound and the second compound. Therefore, the “layer including the mixture of the first compound and the second compound” is clearly distinguished from, for example, a double-layer structure in which a layer containing the first compound and a layer containing the second compound are stacked.

The color control unit 2 may include a quantum dot, an inorganic phosphor, an organic fluorescent material, an organic phosphorescent material, or a combination thereof. In one or more embodiments, the color control unit 2 may include a plurality of quantum dots.

The color control unit 2 may include a first color control element for green conversion and a second color control element for red conversion. The first color control element and the second color control element may be patterned for corresponding pixels capable of emitting a different color of light.

The color control unit 2 may include a first color control element for green conversion, a second color control element for red conversion, and a third color control element for blue conversion. The first color control element, the second color control element, and the third color control element may be patterned for corresponding pixels capable of emitting a different color of light.

In one or more embodiments, each of the first color control element and the second color control element may be a color conversion element.

In one or more embodiments, each of the first color control element and the second color control element may be a quantum dot-containing color conversion element.

In one or more embodiments, the third color control element may be a color conversion element or a color filter.

In one or more embodiments, the third color control element may be a quantum dot-containing color conversion element or an absorption type color filter.

In one or more embodiments, the color control unit 2 may include a first color control element including a first quantum dot for green conversion, a second color control element including a second quantum dot for red conversion, and a third color control element for blue conversion.

In one or more embodiments, the color control unit 2 may further include a first color filter located on the first color control element, and a second color filter located on the second color control element.

The light-emitting device may further include a thin-film transistor (TFT) array substrate including a plurality of TFTs (not shown). The plurality of TFTs of the TFT array substrate may be a device for driving pixel (subpixel) regions of the OLED substrate 1. When the light-emitting device is a top-emission type light-emitting device, the TFT array substrate may be located under or below the OLED substrate 1. When the light-emitting device is a bottom-emission type light-emitting device, the TFT array substrate may be located between the OLED substrate 1 and the color control unit 2.

Located between the OLED substrate 1 and the color control unit 2 may be an optical film (for example, a selective reflection film, a capping layer, or the like) that may control the optical characteristics of the light-emitting device in various ways; an encapsulating member to prevent oxygen and/or moisture from external air from reaching the OLED substrate 1; or the like.

In one or more embodiments, a selective reflection film may be additionally located between the OLED substrate 1 and the color control unit 2.

The selective reflection film may be configured to transmit blue light and green light and to reflect red light. The selective reflection film may act to transmit a wavelength band of about 440 nm to about 550 nm and reflect a wavelength band of about 610 nm to about 760 nm. Accordingly, the mixed light including blue light and green light emitted from the OLED substrate 1 may be irradiated to the color control unit 2 through the selective reflection film. In one or more embodiments, red light emitted downward from the second color control element 70b, which will be described later, may be reflected by the selective reflection film and emitted upward. Accordingly, the optical efficiency may be improved by the selective reflection film. When necessary, the selective reflection film may be optionally formed only under the second color control element 70b, which will be described later.

For example, the selective reflection film may be formed in a distributed Bragg reflector (DBR) structure. A DBR structure that passes or reflects only the desired wavelength band may be created by repeatedly stacking two material layers (dielectrics) having different refractive indices and adjusting the thickness and the number of layers to be stacked of the material layers. The DBR structure may be applied to the selective reflection film. For example, a first dielectric layer and a second dielectric layer may be repeatedly stacked, and the reflectance or transmittance of the desired wavelength band may be increased by adjusting the material, the thickness, and the number of layers to be stacked of the material layers. In one or more embodiments, the selective reflection film may have a dichroic mirror structure.

The light-emitting device may not emit white light.

### Description of First Compound and Second Compound

The first compound emits first light having a first spectrum and λP(1) is a first emission peak wavelength (nm) of the first spectrum, and the second compound emits second light having a second spectrum and λP(2) is a second emission peak wavelength (nm) in the second spectrum. The absolute value of the difference between the λP(1) and λP(2) is from 0 nm to about 30 nm, 0 nm to about 25 nm, 0 nm to about 20 nm, 0 nm to about 15 nm, or 0 nm to about 10 nm, and λP(1) and λP(2) are each independently about 500 nm to about 570 nm, or about 500 nm to about 550 nm. In one or more embodiments, each of λP(1) and λP(2) may independently be about 500 nm to about 540 nm, or about 510 nm to about 540 nm.

λP(1) and λP(2) are evaluated from the photoluminescence (PL) spectra measured with respect to the first film and the second film, respectively, and are emission peak wavelengths in the corresponding photoluminescence spectra, respectively. In other words, λP(1) is evaluated from a first photoluminescence spectrum measured from a first film comprising the first compound and is an emission peak wavelengths in the first photoluminescence spectrum, and λP(2) is evaluated from a second photoluminescence spectrum measured from a second film comprising the second compound and is an emission peak wavelengths in the second photoluminescence spectrum.

The term “first film” as used herein refers to a film including the first compound, and the term “second film” as used herein refers to a film including the second compound. The first film and the second film may be manufactured using various methods, for example, a vacuum deposition method, and a coating and heating method. The first film and the second film may further include a compound, for example, a host described herein, other than the first compound and the second compound.

In one or more embodiments, the first compound and the second compound may each be an emitter.

In one or more embodiments, both the first compound and the second compound may emit a green light.

In one or more embodiments, the first compound and the second compound may each be an emitter, and λP(1) and λP(2) may each independently be about 510 nm to about 540 nm.

In one or more embodiments, the first compound may be a sensitizer, and the second compound may be an emitter.

In one or more embodiments, the first compound may be a sensitizer, the second compound may be an emitter, λP(1) may be about 500 nm to about 520 nm, and λP(2) may be about 510 nm to about 540 nm.

In one or more embodiments, the first compound and the second compound may each be a phosphorescent compound.

The phosphorescent compound may be an organometallic compound containing a transition metal (for example, iridium, platinum, osmium, or the like), and may be electrically neutral.

In one or more embodiments, the phosphorescent compound may be a platinum-containing organometallic compound or an iridium-containing organometallic compound. In one or more embodiments, the platinum-containing organometallic compound may be a platinum-containing organometallic compound including platinum and a tetradentate ligand bonded to the platinum. In one or more embodiments, the tetradentate ligand includes a carbon atom and an oxygen atom (or, a sulfur atom), and the platinum-containing organometallic compound may include a chemical bond between the carbon atom of the tetradentate ligand and the platinum, and a chemical bond between the oxygen atom (or, the sulfur atom) of the tetradentate ligand and the platinum.

In one or more embodiments, the first compound may be a phosphorescent compound, and the second compound may be a fluorescent compound.

In one or more embodiments, the first compound and the second compound may each independently be a fluorescent compound.

The fluorescent compound may be a thermally-activated delayed fluorescence (TADF) compound, or a prompt fluorescent compound.

In one or more embodiments, each of the first compound and the second compound may independently be a fluorescent compound, wherein the first compound may be a thermally-activated delayed fluorescence compound, and the second compound may be a prompt fluorescent compound.

The first compound and the second compound may satisfy Condition 1 or Condition 2:

Condition 1

The first compound is a platinum-containing organometallic compound including platinum and a tetradentate ligand bonded to the platinum, and

the second compound is an iridium-containing organometallic compound.

Condition 2

Each of the first compound and the second compound is independently an iridium-containing organometallic compound.

In one or more embodiments, the first compound and the second compound may satisfy Condition 1,

μ(Pt) may be about 0.5 debye to about 5.0 debye,

μ(Pt) may be less than μ(Ir),

μ(Pt) may be an electric dipole moment of the first compound,

μ(Ir) may be an electric dipole moment of the second compound, and

each of μ(Pt) and μ(Ir) may be calculated based on density functional (DFT) theory. Any various programs may be used for the quantum mechanical calculation based on the DFT, and for example, a Gaussian 16 program may be used.

In the case of a mixture of the first compound and the second compound that satisfy Condition 1, aggregation among molecules of the first compound in the mixture, aggregation among molecules of the second compound in the mixture, and/or aggregation among molecules of the first compound and molecules of the second compound in the mixture, may be substantially minimized. Accordingly, without any consideration about intermolecular aggregation, the amounts (for example, weight) of the first compound and the second compound in the mixture may be relatively increased. Accordingly, a layer including the mixture and a light-emitting device including the mixture may have excellent luminescence efficiency and lifespan characteristics. In addition, when an emission unit of a light-emitting device contains a mixture of the first compound and the second compound which satisfy Condition 1, the hole flux in the emission unit is increased due to the mixture, so that an exciton recombination zone in the emission unit may be spaced apart from each of the interface between an emission layer and a hole transport region and the interface between an emission layer and an electron transport region, resulting in improved lifespan characteristics of the light-emitting device.

The platinum-containing organometallic compound includes one platinum atom and may contain no metal(s) other than platinum.

The platinum-containing organometallic compound may contain no ligands other than the tetradentate ligand bound to the platinum.

The tetradentate ligand bound to platinum in the platinum-containing organometallic compounds may have excellent electrical characteristics and structural rigidity. In addition, the platinum-containing organometallic compound having the tetradentate ligand bound to platinum has a planar structure and may have a relatively small dipole moment. Thus, the layer including the platinum-containing organometallic compound or the light-emitting device including the platinum-containing organometallic compound have excellent luminescence efficiency and a long lifespan.

The iridium-containing organometallic compound contains one iridium atom and may contain no metal(s) other than iridium.

In this specification, the terms “electric dipole moment of the first compound” and “electric dipole moment of the second compound” as used herein may refer to “total permanent dipole moment in the molecule of the first compound” and “total permanent dipole moment in the molecule of the second compound”, respectively.

In one or more embodiments, μ(Pt) may be from about 0.5 debye to about 5.0 debye.

In one or more embodiments, μ(Pt) may be from about 0.5 debye to about 3.0 debye, about 1.0 debye to about 3.0 debye, about 1.5 debye to about 3.0 debye, about 1.7 debye to about 3.0 debye, or about 1.7 debye to about 2.7 debye.

In one or more embodiments, μ(Pt) may be from about 2.0 debye to about 5.0 debye, about 3.0 debye to about 5.0 debye, or about 4.0 debye to about 5.0 debye.

In one or more embodiments, μ(Ir) may be from about 4.0 debye to about 9.0 debye, about 4.5 debye to about 7.5 debye, or about 5.0 debye to about 7.0 debye.

In one or more embodiments, μ(Ir)-μ(Pt) may be from about 0.3 debye to about 4.0 debye.

In one or more embodiments, μ(Ir)-μ(Pt) may be from about 2.0 debye to about 4.0 debye or about 2.0 debye to about 3.0 debye.

In one or more embodiments, μ(Ir)-μ(Pt) may be from about 0.3 debye to about 1.0 debye.

In one or more embodiments, in Condition 1,

λP(Pt) may be equal to λP(Ir),

λP(Pt) may be less than λP(Ir),

λP(Pt) may be greater than λP(Ir),

λP(Pt) and λP(Ir) may each be about 510 nm to about 570 nm,

λP(Pt) and λP(Ir) may each be about 510 nm to about 540 nm,

λP(Pt) may be about 510 nm to about 530 nm, and λP(Ir) may be about 520 nm to about 540 nm,

λP(Pt) and λP(Ir) may each be about 540 nm to about 570 nm, or

λP(Pt) may be about 540 nm to about 560 nm, and λP(Ir) may be about 550 nm to about 570 nm,

wherein λP(Pt) is the first emission peak wavelength λP(1) of the first compound, as evaluated from the first photoluminescence spectrum measured from the first film comprising the first compound, and

λP(Ir) is the second emission peak wavelength λP(2) of the second compound, as evaluated from the second photoluminescence spectrum measured from the second film comprising the second compound.

In one or more embodiments, the light emitting device may satisfy Condition 2, and at least one of Equation 1 to Equation 4. Accordingly, a light-emitting device including the first compound and the second compound satisfying Condition 2 may have better luminescence efficiency and long lifespan:

λP(Ir1)>λP(Ir2) Equation 1

PLQY(Ir1)>PLYQ(Ir2) Equation 2

kᵣ(Ir1)>kᵣ(Ir2) Equation 3

HOR(Ir1)>HOR(Ir2) Equation 4

wherein, in Equation 1,

λP(Ir1) is the first emission peak wavelength λP(1) of the first compound, as evaluated from the first photoluminescence spectrum measured from the first film comprising the first compound, and λP(Ir2) is the second emission peak wavelength λP(2) of the second compound, as evaluated from the second photoluminescence spectrum measured from the second film comprising the second compound.

In relation to Equation 2, PLQY(Ir1) is the first photoluminescence (PL) quantum yield of the first compound, as evaluated from the first PL spectrum measured from the first film comprising the first compound, and PLQY(Ir2) is the second PL quantum yield of the second compound, as evaluated from the second PL spectrum measured from the second film comprising the second compound.

In relation to Equation 3, kr(Ir1) is a first radiative decay rate of the first compound, as evaluated from the first PL spectrum and first time-resolved PL spectra measured from the first film comprising the first compound, and kr(Ir2) is a second radiative decay rate of the second compound, as evaluated from the second PL spectrum and second time-resolved PL spectra measured from the second film comprising the second compound.

In relation to Equation 4, HOR(Ir1) is a first horizontal orientation ratio of the first compound, as evaluated from a first emission intensity with respect to a first angle measured from the first film comprising the first compound, and HOR(Ir2) is a second horizontal orientation ratio of the second compound, as evaluated from a second emission intensity with respect to a second angle measured from the second film comprising the second compound.

The first film and the second film are those described in the present specification.

In one or more embodiments, the light-emitting device including the first compound and the second compound that satisfies Condition 2 may satisfy:

Equation 1,

at least one of Equation 2 to Equation 4, or

Equation 1, and at least one of Equation 2 to Equation 4.

In one or more embodiments, the light-emitting device including the first compound and the second compound that satisfy Condition 2 may further satisfy Equation 5:

HOMO(Ir1)<HOMO(Ir2) Equation 5

wherein, in Equation 5,

HOMO (Ir1) is a first highest occupied molecular orbital (HOMO) energy level of the first compound, as evaluated from a first atmospheric photoelectron spectrum measured from the first film comprising the first compound, and

HOMO (Ir2) is a second highest occupied molecular orbital (HOMO) energy level of the second compound, as evaluated from a second atmospheric photoelectron spectrum measured from the second film comprising the second compound.

Each of HOMO (Ir1) and HOMO (Ir2) may be a negative value measured using an atmospheric photoelectron spectrometer, for example, AC3 manufactured by RIKEN KEIKI Co., Ltd.

Since the light-emitting device including the first compound and the second compound satisfies Condition 2 and satisfies Equation 5, the second compound in the mixture has a shallower HOMO energy level than the first compound, and a relatively greater amount of holes may be trapped in the second compound. As a result, in the case of the light-emitting device including the mixture, without the phenomenon in which the first compound and the second compound are changed into an anionic state due to electrons injected into the mixture and the increase in the driving voltage, holes and electrons may effectively recombine in the first compound and/or the second compound. Accordingly, the light-emitting device may have excellent luminescence efficiency characteristics and excellent lifespan characteristics.

In one or more embodiments, in the light-emitting device including the first compound and the second compound satisfying Condition 2,

|HOMO (Ir1)−HOMO (Ir2)| may be about 0.03 electron volts (eV) to about 0.30 eV, and

|HOMO (Ir1)−HOMO (Ir2)| may be the absolute value of HOMO (Ir1)−HOMO (Ir2).

In one or more embodiments, the platinum-containing organometallic compound in Condition 1 may comprise a chemical bond between a carbon atom of the tetradentate ligand and the platinum, and

a chemical bond between an oxygen atom of the tetradentate ligand and the platinum, and each of the iridium-containing organometallic compounds in Condition 1 and Condition 2 contains a first ligand, a second ligand, and a third ligand,

wherein, in each of the iridium-containing organometallic compounds,

the first ligand, the second ligand, and the third ligand are identical to each other,

the first ligand and the second ligand are identical to each other, and the second ligand and the third ligand are different from each other, or

the first ligand, the second ligand, and the third ligand are different from each other, and

wherein the first ligand, the second ligand, and the third ligand may each be:

a bidentate ligand bonded to the iridium of the iridium-containing organometallic compound via two nitrogen atoms;

a bidentate ligand bonded to the iridium of the iridium-containing organometallic compound via a nitrogen atom and a carbon atom; or

a bidentate ligand bonded to the iridium of the iridium-containing organometallic compound via two carbon atoms.

In one or more embodiments, the platinum-containing organometallic compound may be an organometallic compound represented by Formula 1, and the iridium-containing organometallic compound may be an organometallic compound represented by Formula 2:

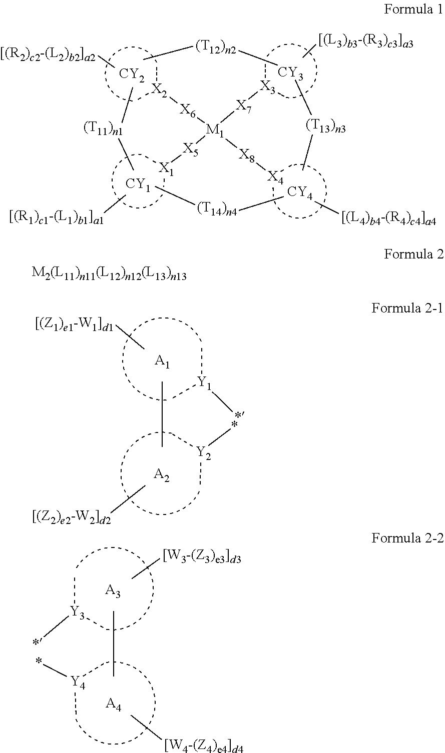

M₁ in Formula 1 may be platinum (Pt),

M₂ in Formula 2 may be iridium (Ir),

L₁₁ in Formula 2 may be a ligand represented by Formula 2-1,

L₁₂ in Formula 2 may be a ligand represented by Formula 2-2,

L₁₃ in Formula 2 may be a ligand represented by Formula 2-1 or 2-2,

L₁₁ and L₁₂ in Formula 2 may be different from each other,

n11, n12 and n13 in Formula 2 may each independently be 0, 1, 2, or 3, and the sum of n11, n12, and n13 may be 3,

X₁ to X₄ and Y₁ to Y₄ in Formulae 1, 2-1, and 2-2 may each independently be C or N,

X₅ to X₈ in Formula 1 may each independently be a chemical bond, *—O—*′, *—S—*′, *—N(R′)—*′, *—C(R′)(R″)—*′, or *—C(═O)—*′, wherein at least one of X₅ to X₈ may not be a chemical bond,

two of a bond between X₅ or X₁ and M₁, a bond between X₆ or X₂ and M₁, a bond between X₇ or X₃ and M₁, and a bond between X₈ or X₄ and M₁ may each be a coordinate bond, and the other two may each be a covalent bond,

ring CY₁ to ring CY₄ and ring A₁ to ring A₄ in Formulae 1, 2-1, and 2-2 may each independently be a C₅-C₃₀ carbocyclic group or a C₁-C₃₀ heterocyclic group,

T₁₁ to T₁₄ in Formula 1 may each independently be a single bond, a double bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*′, *—C(R₅ₐ)═*′, *═C(R₅ₐ)—*′, *—C(R₅ₐ)═C(R_{5b})—*′, *—C(═S)—*′, *—C≡C—*′, a C₅-C₃₀ carbocyclic group that is unsubstituted or substituted with at least one R₁₀ₐ, or a C₁-C₃₀ heterocyclic group that is unsubstituted or substituted with at least one R₁₀ₐ,

n1 to n4 in Formula 1 may each independently be 0 or 1, and 3 or more of n1 to n4 may each be 1,

when n1 is 0, T₁₁ does not exist, when n2 is 0, T₁₂ does not exist, when n3 is 0, T₁₃ does not exist, when n4 is 0, T₁₄ does not exist,

L₁ to L₄ and W₁ to W₄ in Formulae 1, 2-1, and 2-2 may each independently be a single bond, a C₁-C₂₀ alkylene group that is unsubstituted or substituted with at least one R₁₀ₐ, a C₅-C₃₀ carbocyclic group that is unsubstituted or substituted with at least one R₁₀ₐ, or a C₁-C₃₀ heterocyclic group that is unsubstituted or substituted with at least one R₁₀ₐ,

b1 to b4 in Formula 1 may each independently be an integer of 1 to 10,

R₁ to R₄, R₅ₐ, R_{5b}, R′, R″, and Z₁ to Z₄ in Formulae 1, 2-1, and 2-2 may each independently be hydrogen, deuterium, —F, —Cl, —Br, —I, —SF₅, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

c1 to c4, a1 to a4, e1 to e4, and d1 to d4 in Formulae 1, 2-1, and 2-2 may each independently be an integer of 0 to 20,

the second compound may not be tris[2-phenylpyridine]iridium,

two or more substituents in at least one of i) two or more of a plurality of R₁(s), ii) two or more of a plurality of R₂(s), iii) two or more of a plurality of R₃(s), iv) two or more of a plurality of R₄(s), v) R₅ₐ and R_{5b}, vi) two or more of a plurality of Z₁(s), vii) two or more of a plurality of Z₂(s), viii) two or more of a plurality of Z₃(s), ix) two or more of a plurality of Z₄(s), x) two or more of R₁ to R₄, R₅ₐ, and R_{5b}, and xi) two or more of Z₁ to Z₄ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,

R₁₀ₐ is understood by referring to the description of R₁ provided herein,

* and *′ in Formulae 2-1 and 2-2 each indicate a binding site to M₂,

* and *′ in X₅ to X₈ and T₁₁ to T₁₄ each indicate a binding site to an adjacent atom, and

at least one substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:

deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or

a combination thereof,

wherein Q₁ to Q₉, Q₁₁ to Q₁₉, Q₂₁ to Q₂₉, and Q₃₁ to Q₃₉ may each independently be: hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

Platinum (Pt) as M₁ in Formula 1 may be replaced by palladium (Pd) or gold (Au). That is, the platinum-containing organometallic compound may be replaced with a palladium-containing or a gold-containing organometallic compound.

In Formula 2, n11 to n13 each indicates the number of L₁₁(s) to the number of L₁₃(s), respectively, and may each independently be 0, 1, 2, or 3, wherein n11+n12+n13 may be 3.

In one or more embodiments, in Formula 2, n11 may be 1, 2, or 3, and n12 and n13 may each independently be 0, 1, or 2.

In one or more embodiments, in Formula 2, n12 may be 1, 2, or 3, and n11 and n13 may each independently be 0, 1, or 2.

In one or more embodiments, n11 may be 1, n12 may be 2, and n13 may be 0.

In one or more embodiments, n11 may be 2, n12 may be 1, and n13 may be 0.

In one or more embodiments, n11 may be 3, and n12 and n13 may each be 0.

In one or more embodiments, n12 may be 3, and n11 and n13 may each be 0.

The iridium-containing organometallic compound represented by Formula 2 may be a heteroleptic complex or a homoleptic complex.

In one or more embodiments, the iridium-containing organometallic compound may be a heteroleptic complex.

In Formulae 1, 2-1, and 2-2, X₁ to X₄ and Y₁ to Y₄ may each independently be C or N.

In one or more embodiments, at least one of X₁ to X₄ in Formula 1 may be C.

In one or more embodiments, X₁ in Formula 1 may be C.

In one or more embodiments, in Formula 1, i) X₁ and X₃ may each be C, and X₂ and X₄ may each be N, or ii) X₁ and X₄ may each be C, and X₂ and X₃ may each be N.

In one or more embodiments, in Formulae 2-1 and 2-2, Y₁ and Y₃ may each be N, and Y₂ and Y₄ may each be C.

In Formula 1, X₅ to X₈ may each independently be a chemical bond, *—O—*′, *—S—*′ *—N(R′)—*′, *—C(R′)(R″)—*′, or *—C(═O)—*′, wherein at least one of X₅ to X₈ may not be a chemical bond, and * and *′ each indicated a bonding site to an adjacent atom. R′ and R″ may each be the same as described herein.

In one or more embodiments, X₅ in Formula 1 may not be a chemical bond.

In one or more embodiments, X₅ in Formula 1 may be O or S.

In one or more embodiments, in Formula 1, X₅ may be O or S, and X₅ to X₈ may each be a chemical bond.

In Formula 1, two bonds of a bond between X₅ or X₁ and M₁, a bond between X₅ or X₂ and M₁, a bond between X₇ or X₃ and M₁, and a bond between X₈ or X₄ and M₁ may each be a coordinate bond, and the other two bonds may each be a covalent bond.

In one or more embodiments, a bond between X₂ and M in Formula 1 may be a coordinate bond.

In one or more embodiments, in Formula 1, a bond between X₅ or X₁ and M and a bond between X₃ and M may each be a covalent bond, and a bond between X₂ and M and a bond between X₄ and M may each be a coordinate bond.

In one or more embodiments, the platinum-containing organometallic compound and iridium-containing organometallic compound may each be electrically neutral.

In Formulae 1, 2-1, and 2-2, ring CY₁ to ring CY₄ and ring A₁ to ring A₄ may each independently be a C₅-C₃₀ carbocyclic group or a C₁-C₃₀ heterocyclic group.

For example, each of ring CY₁, ring CY₃, and ring CY₄ may not be a benzimidazole group.

For example, in Formulae 1, 2-1, and 2-2, ring CY₁ to ring CY₄ and ring A₁ to A₄ may each independently be i) a first ring, ii) a second ring, iii) a condensed ring in which two or more first rings are condensed with each other, iv) a condensed ring in which two or more second rings are condensed with each other, or v) a condensed ring in which one or more first rings are condensed with one or more second rings,

wherein the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

the second ring may be an adamantane group, a norbornane group, a norbornene group, a piperidine group, a cyclohexane group, a cyclohexene group, a benzene group, a pyridine group, a pyrimidine group, a pyrazine group, a pyridazine group, or a triazine group.

In one or more embodiments, in Formulae 1, 2-1, and 2-2, ring CY₁ to ring CY₄ and ring A₁ to ring A₄ may each independently be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, a pyrrole group, a furan group, a thiophene group, a silole group, a borole group, a phosphole group, a germole group, a selenophene group, an indene group, an indole group, a benzofuran group, a benzothiophene group, a benzosilole group, a benzoborole group, a benzophosphole group, a benzogermole group, a benzoselenophene group, a fluorene group, a carbazole group, a dibenzofuran group, a dibenzothiophene group, a dibenzosilole group, a dibenzoborole group, a dibenzophosphole group, a dibenzogermole group, a dibenzoselenophene group, a benzofluorene group, a benzocarbazole group, a naphthobenzofuran group, a naphthobenzothiophene group, a naphthobenzosilole group, a naphthobenzoborole group, a naphthobenzophosphole group, a naphthobenzogermole group, a naphthobenzoselenophene group, a dibenzofluorene group, a dibenzocarbazole group, a dinaphthofuran group, a dinaphthothiophene group, a dinaphthosilole group, a dinaphthoborole group, a dinaphthophosphole group, a dinaphthogermole group, a dinaphthoselenophene group, an indenophenanthrene group, an indolophenanthrene group, a phenanthrobenzofuran group, a phenanthrobenzothiophene group, a phenanthrobenzosilole group, a phenanthrobenzoborole group, a phenanthrobenzophosphole group, a phenanthrobenzogermole group, a phenanthrobenzoselenophene group, a dibenzothiophene 5-oxide group, a 9H-fluorene-9-one group, a dibenzothiophene 5,5-dioxide group, an azaindene group, an azaindole group, an azabenzofuran group, an azabenzothiophene group, an azabenzosilole group, an azabenzoborole group, an azabenzophosphole group, an azabenzogermole group, an azabenzoselenophene group, an azafluorene group, an azacarbazole group, an azadibenzofuran group, an azadibenzothiophene group, an azadibenzosilole group, an azadibenzoborole group, an azadibenzophosphole group, an azadibenzogermole group, an azadibenzoselenophene group, an azabenzofluorene group, an azabenzocarbazole group, an azanaphthobenzofuran group, an azanaphthobenzothiophene group, an azanaphthobenzosilole group, an azanaphthobenzoborole group, an azanaphthobenzophosphole group, an azanaphthobenzogermole group, an azanaphthobenzoselenophene group, an azadibenzofluorene group, an azadibenzocarbazole group, an azadinaphthofuran group, an azadinaphthothiophene group, an azadinaphthosilole group, an azadinaphthoborole group, an azadinaphthophosphole group, an azadinaphthogermole group, an azadinaphthoselenophene group, an azaindenophenanthrene group, an azaindolophenanthrene group, an azaphenanthrobenzofuran group, an azaphenanthrobenzothiophene group, an azaphenanthrobenzosilole group, an azaphenanthrobenzoborole group, an azaphenanthrobenzophosphole group, an azaphenanthrobenzogermole group, an azaphenanthrobenzoselenophene group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a benzoquinoline group, a benzoisoquinoline group, a benzoquinoxaline group, a benzoquinazoline group, a phenanthroline group, a phenanthridine group, a pyrrole group, a pyrazole group, imidazole group, a triazole group, an oxazole group, an isoxazole group, a thiazole group, an isothiazole group, an oxadiazole group, a thiadiazole group, an azasilole group, an azaborole group, an azaphosphole group, an azagermole group, an azaselenophene group, a benzopyrrole group, a benzopyrazole group, a benzimidazole group, a benzoxazole group, a benzisoxazole group, a benzothiazole group, a benzisothiazole group, a benzoxadiazole group, a benzothiadiazole group, a pyridinopyrrole group, a pyridinopyrazole group, a pyridinoimidazole group, a pyridinooxazole group, a pyridinoisoxazole group, a pyridinothiazole group, a pyridinoisothiazole group, a pyridinooxadiazole group, a pyridinothiadiazole group, a pyrimidinopyrrole group, a pyrimidinopyrazole group, a pyrimidinoimidazole group, a pyrimidinooxazole group, a pyrimidinoisoxazole group, a pyrimidinothiazole group, a pyrimidinoisothiazole group, a pyrimidinooxadiazole group, a pyrimidinothiadiazole group, a naphthopyrrole group, a naphthopyrazole group, a naphthoimidazole group, a naphthoxazole group, a naphthoisoxazole group, a naphthothiazole group, a naphthoisothiazole group, a naphthoxadiazole group, a naphthothiadiazole group, a phenanthrenopyrrole group, a phenanthrenopyrazole group, a phenanthrenoimidazole group, a phenanthrenoxazole group, a phenanthrenoisoxazole group, a phenanthrenothiazole group, a phenanthrenoisothiazole group, a phenanthrenoxadiazole group, a phenanthrenothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, a benzene group condensed with a norbornane group, a pyridine group condensed with a cyclohexane group, or a pyridine group condensed with a norbornane group.

In one or more embodiments, ring CY₁ and ring CY₃ in Formula 1 may each independently be:

a benzene group, a naphthalene group, a phenanthrene group, a dibenzofuran group, a dibenzothiophene group, a dibenzoselenophene group, a carbazole group, a fluorene group, or a dibenzosilole group, or

a benzene group, a naphthalene group, a phenanthrene group, a dibenzofuran group, a dibenzothiophene group, a dibenzoselenophene group, a carbazole group, a fluorene group, or a dibenzosilole group, each condensed with at least one of a cyclohexane group, a cyclohexene group, a norbornane group, a piperidine group, or a combination thereof.

In one or more embodiments, ring CY₂ in Formula 1 may be:

an imidazole group, a benzimidazole group, a pyridine group, a pyrimidine group, a pyridazine group, a pyrazine group, a triazine group, a quinoline group, an isoquinoline group, a quinoxaline group, or a quinazoline group; or

an imidazole group, a benzimidazole group, a pyridine group, a pyrimidine group, a pyridazine group, a pyrazine group, a triazine group, a quinoline group, an isoquinoline group, a quinoxaline group, or a quinazoline group, each condensed with at least one of a cyclohexane group, a cyclohexene group, a norbornane group, a benzene group, a pyridine group, a pyrimidine group, or a combination thereof.

In one or more embodiments, ring CY₄ in Formula 1 may be:

a pyridine group, a pyrimidine group, a pyridazine group, a pyrazine group, a triazine group, a quinoline group, an isoquinoline group, a quinoxaline group, a quinazoline group, an azadibenzofuran group, an azadibenzothiophene group, an azadibenzoselenophene group, an azacarbazole group, an azafluorene group, or an azadibenzosilole group; or

a pyridine group, a pyrimidine group, a pyridazine group, a pyrazine group, a triazine group, a quinoline group, an isoquinoline group, a quinoxaline group, a quinazoline group, an azadibenzofuran group, an azadibenzothiophene group, an azadibenzoselenophene group, an azacarbazole group, an azafluorene group, or an azadibenzosilole group, each condensed with at least one of a cyclohexane group, a cyclohexene group, a norbornane group, a benzene group, a pyridine group, a pyrimidine group, or a combination thereof.

In Formulae 2-1 and 2-2, ring A₁ and ring A₃ may be the same as or different from each other.

In one or more embodiments, a Y₁-containing monocyclic group in ring A₁, a Y₂-containing monocyclic group in ring A₂, and Y₄-containing monocyclic group in ring A₄ may each be a 6-membered ring.

In one or more embodiments, a Y₃-containing monocyclic group in ring A₃ may be a 6-membered ring.

In one or more embodiments, a Y₃-containing monocyclic group in ring A₃ may be a 5-membered ring.

In one or more embodiments, a Y₁-containing monocyclic group in ring A₁ may be a 6-membered ring, and a Y₃-containing monocyclic group in ring A₃ may be a 5-membered ring.

In one or more embodiments, in Formulae 2-1 and 2-2, ring A₁ and ring A₃ may each independently be i) one of Group A, ii) a polycyclic group in which two or more of Group A are condensed with each other, or iii) a polycyclic group in which at least one of Group A and at least one of Group B are condensed with each other,

wherein Group A may include a pyridine group, a pyrimidine group, a pyridazine group, a pyrazine group, or a triazine group, and

Group B may include a cyclohexane group, a cyclohexene group, a norbornane group, a benzene group, a furan group, a thiophene group, a selenophene group, a pyrrole group, a cyclopentadiene group, or silole group.

In one or more embodiments, in Formula 2-2, ring A₃ may be i) one of Group C, ii) a polycyclic group in which two or more of Group C are condensed with each other, or iii) a polycyclic group in which at least one of Group C and at least one of Group D are condensed with each other,

wherein Group C may include a pyrrole group, a pyrazole group, an imidazole group, a triazole group, an oxazole group, an isoxazole group, a thiazole group, or an isothiazole group, and

Group D may include a cyclohexane group, a cyclohexene group, a norbornane group, a benzene group, a furan group, a thiophene group, a selenophene group, a cyclopentadiene group, a silole group, a pyridine group, a pyrimidine group, a pyridazine group, a pyrazine group, or a triazine group.

In one or more embodiments, ring A₁ in Formula 2-1 may be:

a pyridine group, a pyrimidine group, a pyridazine group, or a pyrazine group; or

a pyridine group, a pyrimidine group, a pyridazine group, or a pyrazine group, each condensed with at least one of a cyclohexane group, a norbornane group, a benzene group, or a combination thereof.

In one or more embodiments, ring A₃ in Formula 2-2 may be:

a pyridine group, a pyrimidine group, a pyridazine group, or a pyrazine group;

a pyridine group, a pyrimidine group, a pyridazine group, or a pyrazine group, each condensed with at least one of a cyclohexane group, a norbornane group, a benzene group, or a combination thereof; or

an imidazole group, a benzimidazole group, a naphthoimidazole group, a phenanthrenoimidazole group, a pyridoimidazole group, an oxazole group, a benzoxazole group, a naphthooxazole group, a phenanthrenoxazole group, a pyridooxazole group, a thiazole group, a benzothiazole group, a naphthothiazole group, a phenanthrenothiazole group, or a pyridothiazole group.

In one or more embodiments, ring A₂ and ring A₄ in Formulae 2-1 and 2-2 may be different from each other.

In one or more embodiments, in Formulae 2-1 and 2-2, ring A₂ and ring A₄ may each independently be i) one of Group E, ii) a polycyclic group in which two or more of Group E are condensed with each other, or iii) a polycyclic group in which at least one of Group E and at least one of Group F are condensed with each other,

wherein Group E may include a benzene group, a pyridine group, a pyrimidine group, a pyridazine group, a pyrazine group, or a triazine group, and

Group F may include a furan group, a thiophene group, a selenophene group, a pyrrole group, a cyclopentadiene group, a silole group, a pyrazole group, an imidazole group, an oxazole group, a thiazole group, an isoxazole group, or an isothiazole group.

In one or more embodiments, in Formula 2-1, ring A₂ may be a polycyclic group in which two or more of Group E and at least one of Group F are condensed with each other.

In one or more embodiments, in Formula 2-2, ring A₄ may be a polycyclic group in which two or more of Group E and at least one of Group F are condensed with each other.

In one or more embodiments, ring A₂ in Formula 2-1 may be:

a benzene group, a naphthalene group, a phenanthrene group, a dibenzofuran group, a dibenzothiophene group, a dibenzoselenophene group, a carbazole group, a fluorene group, or a dibenzosilole group; or

a benzene group, a naphthalene group, a phenanthrene group, a dibenzofuran group, a dibenzothiophene group, a dibenzoselenophene group, a carbazole group, a fluorene group, or a dibenzosilole group, each condensed with at least one of a cyclohexane group, a norbornane group, a benzene group, or a combination thereof.

In one or more embodiments, ring A₄ in Formula 2-2 may be:

a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group; or

a benzene group, a naphthalene group, a phenanthrene group, a dibenzofuran group, a dibenzothiophene group, a dibenzoselenophene group, a carbazole group, a fluorene group, a dibenzosilole group, an azadibenzofuran group, an azadibenzothiophene group, an azadibenzoselenophene group, an azacarbazole group, an azafluorene group, or a dibenzosilole group, each condensed with at least one of a benzene group, a pyridine group, a pyrimidine group, a pyridazine group, a pyrazine group, a cyclohexane group, a norbornane group, a furan group, a thiophene group, a selenophene group, a pyrrole group, a cyclopentadiene group, a silole group, a pyrazole group, an imidazole group, an oxazole group, a thiazole group, an isoxazole group, an isothiazole group, or a combination thereof.

In Formula 1, T₁₁ to T₁₄ may each independently be a single bond, a double bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, *—Se—*′, *—O—*′, *—C(═O)—*′, *—S(═O)—*′, *—S(═O)₂—*′ *—C(R₅ₐ)═*′, *═C(R₅ₐ)—*′, *—C(R₅ₐ)═C(R_{5b})—*′, *—C(═S)—*′, *—C≡C—*′, a C₅-C₃₀ carbocyclic group that is unsubstituted or substituted with at least one R₁₀ₐ, or a C₁-C₃₀ heterocyclic group that is unsubstituted or substituted with at least one R₁₀ₐ, wherein * and *′ each indicates a binding site to an adjacent atom.

In one or more embodiments, T₁₁ and T₁₂ in Formula 1 may be a single bond, and T₁₃ may be a single bond, *—N(R₅ₐ)—*′, *—B(R₅ₐ)—*′, *—P(R₅ₐ)—*′, *—C(R₅ₐ)(R_{5b})—*′, *—Si(R₅ₐ)(R_{5b})—*′, *—Ge(R₅ₐ)(R_{5b})—*′, *—S—*′, or *—O*′, wherein * and *′ each indicates a binding site to an adjacent atom.

n1 to n4 in Formula 1 indicate numbers of T₁₁ to T₁₄, respectively, and may each independently be 0 or 1, wherein three or more of n1 to n4 may each be 1. That is, an organometallic compound represented by Formula 1 may have a tetradentate ligand.

In Formula 1, when n1 is 0, T₁₁ does not exist (that is, ring CY₁ and ring CY₂ are not linked to each other), when n2 is 0, T₁₂ does not exist (that is, ring CY₂ and ring CY₃ are not linked to each other), when n3 is 0, T₁₃ does not exist (that is, ring CY₃ and ring CY₄ are not linked to each other), and when n4 is 0, T₁₄ does not exist (that is, ring CY₄ and ring CY₁ are not linked to each other).

In one or more embodiments, in Formula 1, n1 to n3 may each be 1, and n4 may be 0.

L₁ to L₄ and W₁ to W₄ in Formulae 1, 2-1, and 2-2 may each independently be a single bond, a C₁-C₂₀ alkylene group that is unsubstituted or substituted with at least one R₁₀ₐ, a C₅-C₃₀ carbocyclic group that is unsubstituted or substituted with at least one R₁₀ₐ, or a C₁-C₃₀ heterocyclic group that is unsubstituted or substituted with at least one R₁₀ₐ.

In one or more embodiments, in Formulae 1, 2-1, and 2-2, L₁ to L₄ and W₁ to W₄ may each independently be:

a single bond, or

a C₁-C₂₀ alkylene group, a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an iso-oxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group, each unsubstituted or substituted with at least one R₁₀ₐ.

In one or more embodiments, L₁ to L₄ and W₁ to W₄ in Formulae 1, 2-1, and 2-2 may each independently be:

a single bond; or

a C₁-C₂₀ alkylene group, a benzene group, a naphthalene group, a pyridine group, a fluorene group, a carbazole group, a dibenzofuran group, or a dibenzothiophene group, each unsubstituted or substituted with at least one R₁₀ₐ.

In one or more embodiments, in Formulae 1, 2-1, and 2-2, L₁ to L₄ and W₁ to W₄ may each independently be:

a single bond; or

a C₁-C₂₀ alkylene group, a benzene group, a naphthalene group, a dibenzofuran group, or a dibenzothiophene group, each unsubstituted or substituted with at least one of deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

b₁ to b₄ in Formula 1 indicate the number of L₁(s) to the number of L₄(s), respectively, and may each independently be an integer from 1 to 10. When b₁ is 2 or more, two or more of L₁(s) may be identical to or different from each other, when b2 is 2 or more, two or more of L₂(s) may be identical to or different from each other, when b3 is 2 or more, two or more of L₃(s) may be identical to or different from each other, and when b₄ is 2 or more, two or more of L₄(s) may be identical to or different from each other. For example, b₁ to b₄ may each independently be 1, 2, or 3.

R₁ to R₄, R₅ₐ, R_{5b}, R′, R″, and Z₁ to Z₄ in Formulae 1, 2-1, and 2-2 may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ may each be as described herein.

In one or more embodiments, R₁ to R₄, R₅ₐ, R_{5b}, R, R″, and Z₁ to Z₄ in Formulae 1, 2-1, and 2-2 may each independently be:

hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₂-C₂₀ alkenyl group, a C₁-C₂₀ alkoxy group, or a C₁-C₂₀ alkylthio group;

a C₁-C₂₀ alkyl group, a C₂-C₂₀ alkenyl group, a C₁-C₂₀ alkoxy group, or a C₁-C₂₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group (a bicyclo[2.2.1]heptyl group), a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or a combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a fluorinated C₁-C₂₀ alkyl group, a C₁-C₂₀ alkoxy group, a C₁-C₂₀ alkylthio group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a deuterated phenyl group, a fluorinated phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or a combination thereof; or

—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

wherein Q₁ to Q₉ may each independently be:

deuterium, —F, —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, —CF₃, —CF₂H, —CFH₂, —CH₂CF₃, —CH₂CF₂H, —CH₂CFH₂, —CHFCH₃, —CHFCF₂H, —CHFCFH₂, —CHFCF₃, —CF₂CF₃, —CF₂CF₂H, or —CF₂CFH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, —F, C₁-C₁₀ alkyl group, a phenyl group, or a combination thereof.

In one or more embodiments, in Formulae 1, 2-1, and 2-2, R₁ to R₄, R₅ₐ, R_{5b}, R, R″, and Z₁ to Z₄ may each independently be:

hydrogen, deuterium, —F, or a cyano group;

a C₁-C₂₀ alkyl group unsubstituted or substituted with at least one of deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof;

a C₃-C₁₀ cycloalkyl group, a C₁-C₁₀ heterocycloalkyl group, a phenyl group, a biphenyl group, a naphthyl group, a pyridinyl group, a fluorenyl group, a carbazolyl group, a dibenzofuranyl, or a dibenzothiophenyl group, each unsubstituted or substituted with at least one of deuterium, —F, a cyano group, a C₁-C₂₀ alkyl group, a deuterated C₁-C₂₀ alkyl group, fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁-C₁₀ heterocycloalkyl group, a (C₁-C₂₀ alkyl)C₁-C₁₀ heterocycloalkyl group, a phenyl group, a deuterated phenyl group, a fluorinated phenyl group, a (C₁-C₂₀ alkyl)phenyl group, a biphenyl group, a deuterated biphenyl group, a fluorinated biphenyl group, a (C₁-C₂₀ alkyl)biphenyl group, a dibenzofuranyl group, a deuterated dibenzofuranyl group, a fluorinated dibenzofuranyl group, a (C₁-C₂₀ alkyl)dibenzofuranyl group, a dibenzothiophenyl group, a deuterated dibenzothiophenyl group, a fluorinated dibenzothiophenyl group, a (C₁-C₂₀ alkyl)dibenzothiophenyl group, or a combination thereof; or

—Si(Q₃)(Q₄)(Q₅) or —Ge(Q₃)(Q₄)(Q₅).

In one or more embodiments, in Formula 2-1, each of e1 and d1 may not be 0, and at least one of a plurality of Z₁(s) may be a deuterated C₁-C₂₀ alkyl group, —Si(Q₃)(Q₄)(Q₅), or —Ge(Q₃)(Q₄)(Q₅). Q₃ to Q₅ are as described in the present specification.

For example, Q₃ to Q₅ may each independently be:

a C₁-C₆₀ alkyl group unsubstituted or substituted with at least one of deuterium, a C₁-C₆₀ alkyl group, a C₆-C₆₀ aryl group, or a combination thereof; or

a C₁-C₆₀ aryl group unsubstituted or substituted with at least one of deuterium, a C₁-C₆₀ alkyl group, a C₆-C₆₀ aryl group, or a combination thereof.

In one or more embodiments, Q₃ to Q₅ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

In one or more embodiments, Q₃ to Q₅ may be identical to each other.

In one or more embodiments, two or more of Q₃ to Q₅ may be different from each other.

In one or more embodiments, the iridium-containing organometallic compound may satisfy at least one of Condition 10-1 to Condition 10-8:

Condition 10-1

Each of e1 and d1 in Formula 2-1 is not 0, and at least one Z₁ includes deuterium.

Condition 10-2

Each of e2 and d2 in Formula 2-1 is not 0, and at least one Z₂ includes deuterium.

Condition 10-3

Each of e3 and d3 in Formula 2-2 is not 0, and at least one Z₃ includes deuterium.

Condition 10-4

Each of e4 and d4 in Formula 2-2 is not 0, and at least one Z₄ includes deuterium.

Condition 10-5

Each of e1 and d1 in Formula 2-1 is not 0, and at least one Z₁ includes a fluoro group.

Condition 10-6

Each of e2 and d2 in Formula 2-1 is not 0, and at least one Z₂ includes a fluoro group.

Condition 10-7

Each of e3 and d3 in Formula 2-2 is not 0, and at least one Z₃ includes a fluoro group.

Condition 10-8

Each of e4 and d4 in Formula 2-2 is not 0, and at least one Z₄ includes a fluoro group.

In one or more embodiments, in Formulae 1, 2-1, and 2-2, R₁ to R₄, R₅ₐ, R_{5b}, R, R″, and Z₁ to Z₄ may each independently be hydrogen, deuterium, —F, —CH₃, —CD₃, —CD₂H, —CDH₂, —CF₃, —CF₂H, —CFH₂, a C₂-C₁₀ alkenyl group, a C₁-C₁₀ alkoxy group, a C₁-C₁₀ alkylthio group, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-227, a group represented by one of Formulae 9-201 to 9-227 in which at least one hydrogen is substituted with deuterium, a group represented by one of Formulae 9-201 to 9-227 in which at least one hydrogen is substituted with —F, a group represented by one of Formulae 10-1 to 10-129, a group represented by one of Formulae 10-1 to 10-129 in which at least one hydrogen is substituted with deuterium, a group represented by one of Formulae 10-1 to 10-129 in which at least one hydrogen is substituted with —F, a group represented by one of Formulae 10-201 to 10-350, a group represented by one of Formulae 10-201 to 10-350 in which at least one hydrogen is substituted with deuterium, a group represented by one of Formulae 10-201 to 10-350 in which at least one hydrogen is substituted with —F, —Si(Q₃)(Q₄)(Q₅), or —Ge(Q₃)(Q₄)(Q₅) (Q₃ to Q₅ may each be as described herein):

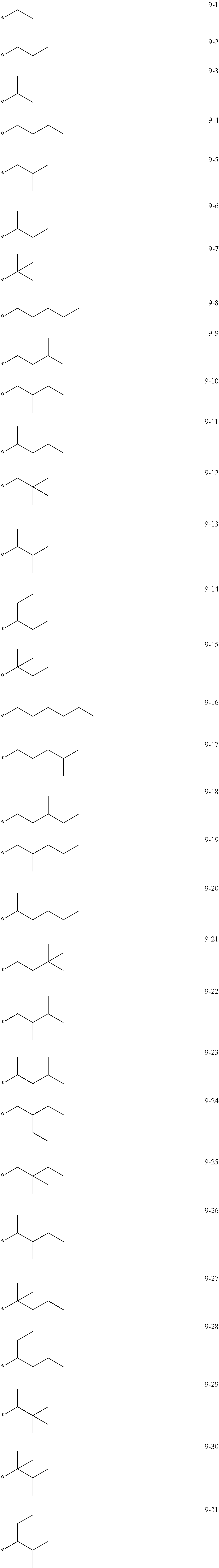

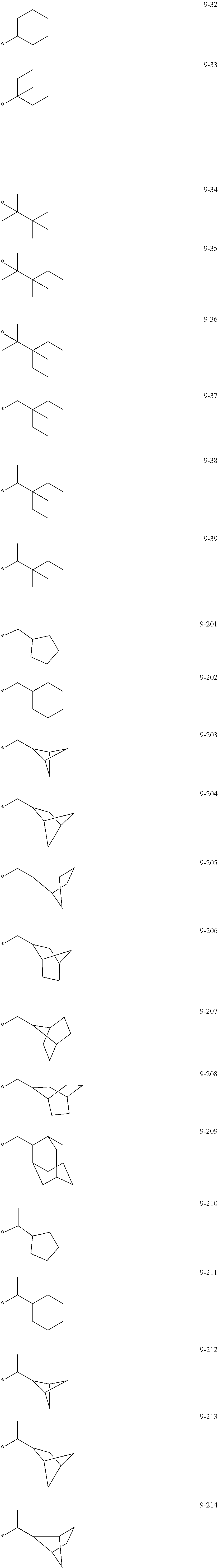

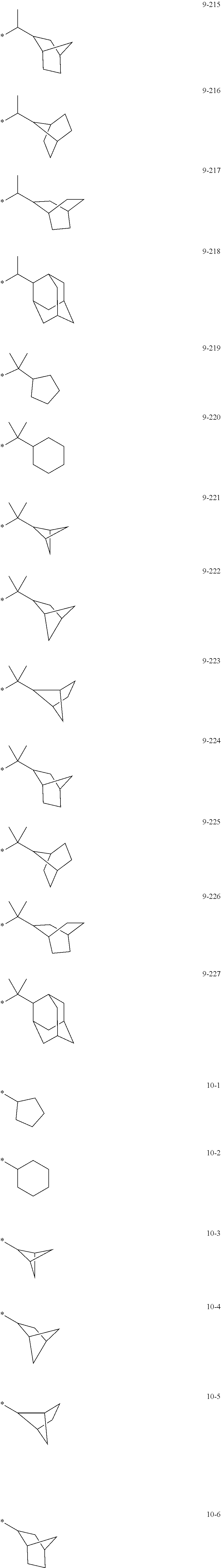

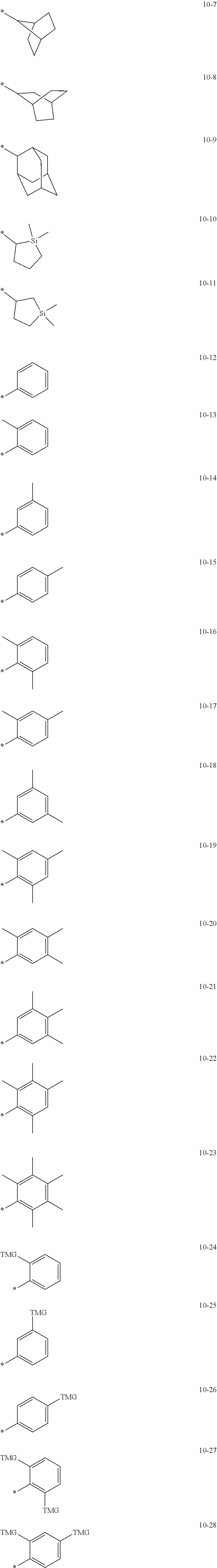

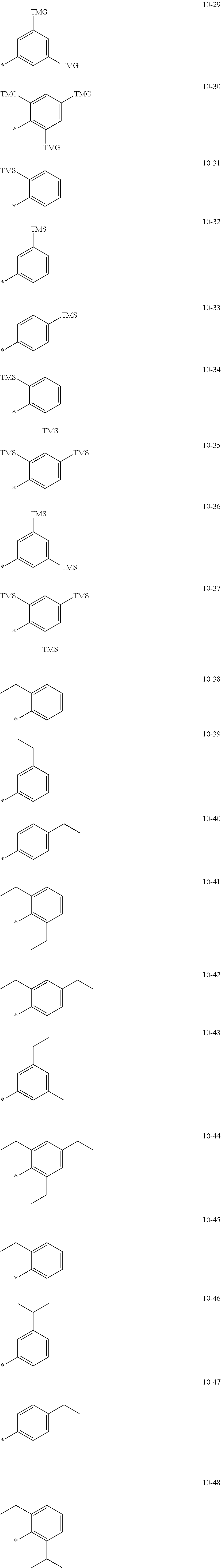

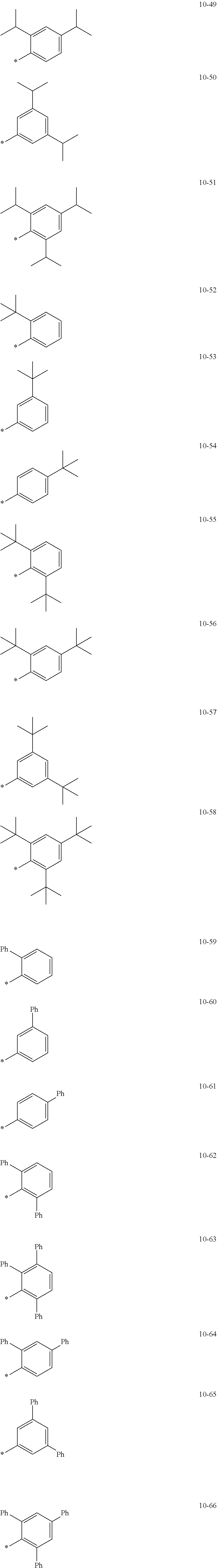

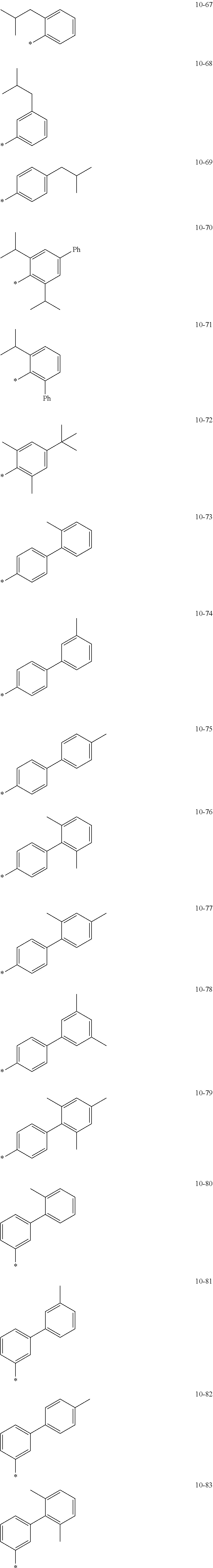

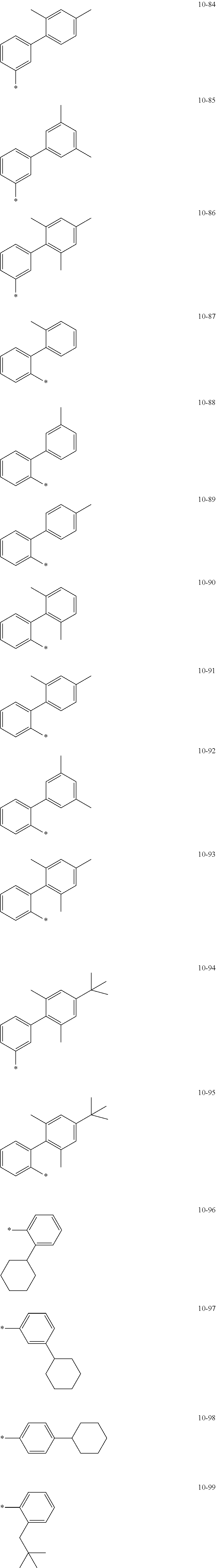

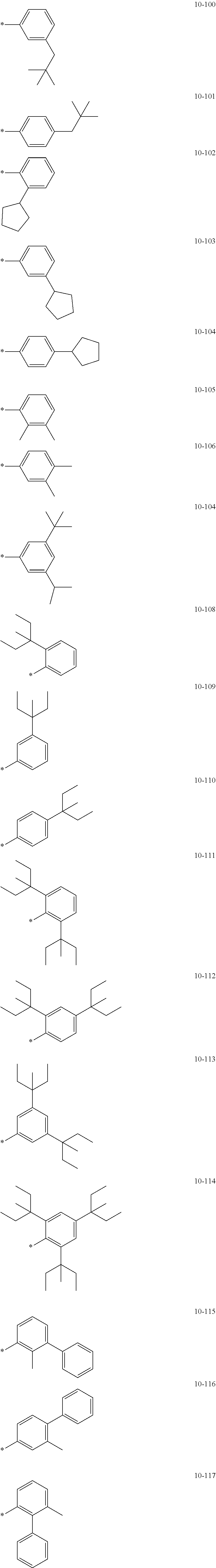

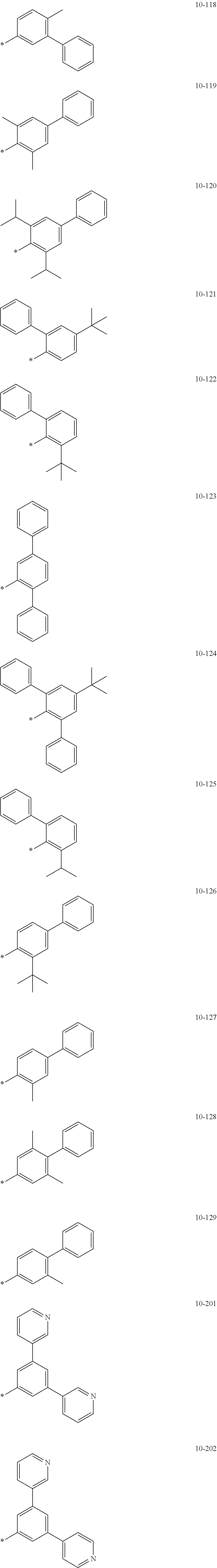

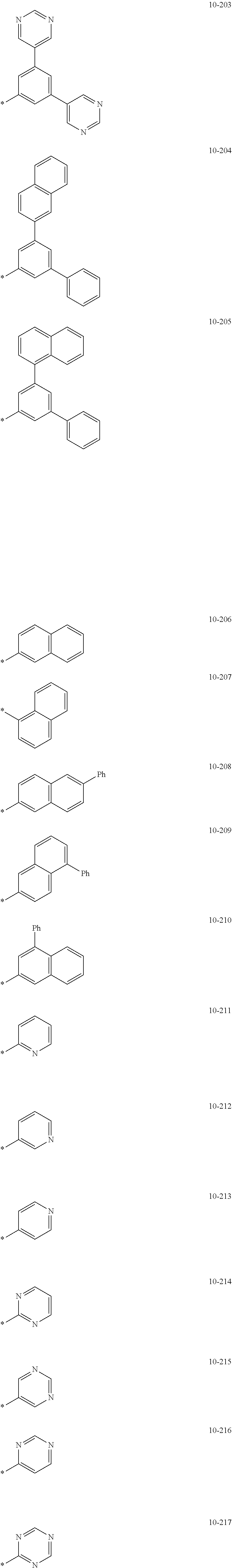

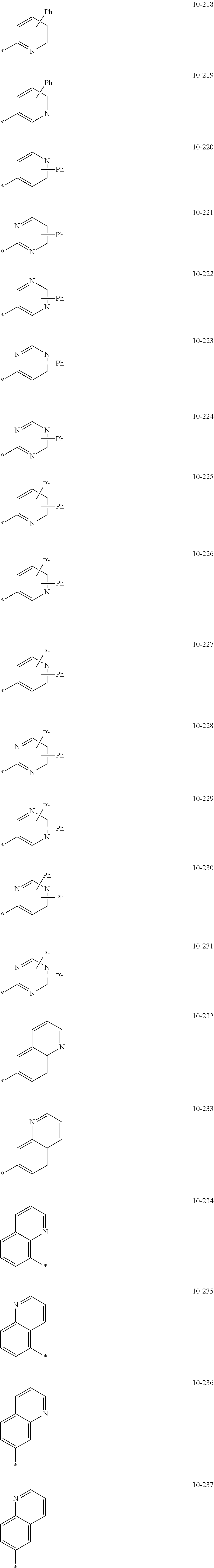

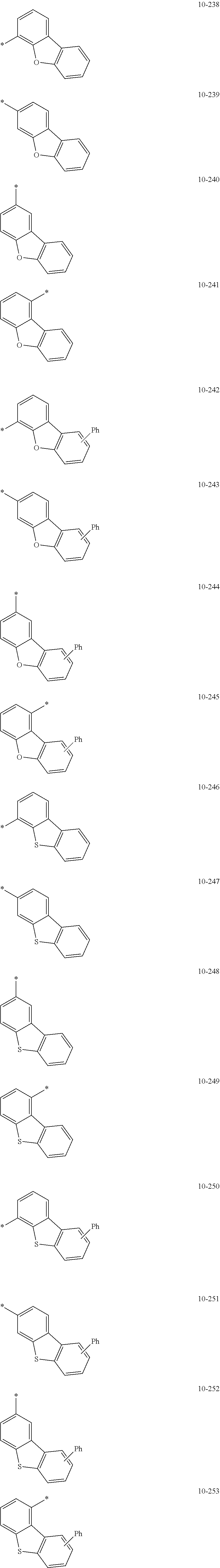

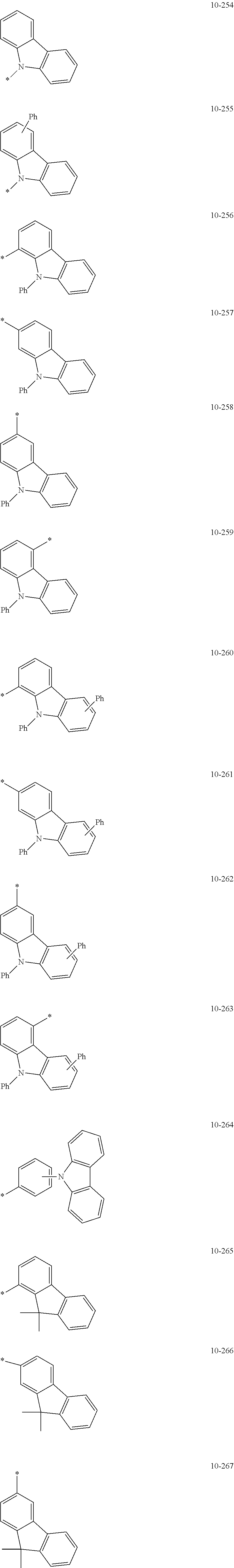

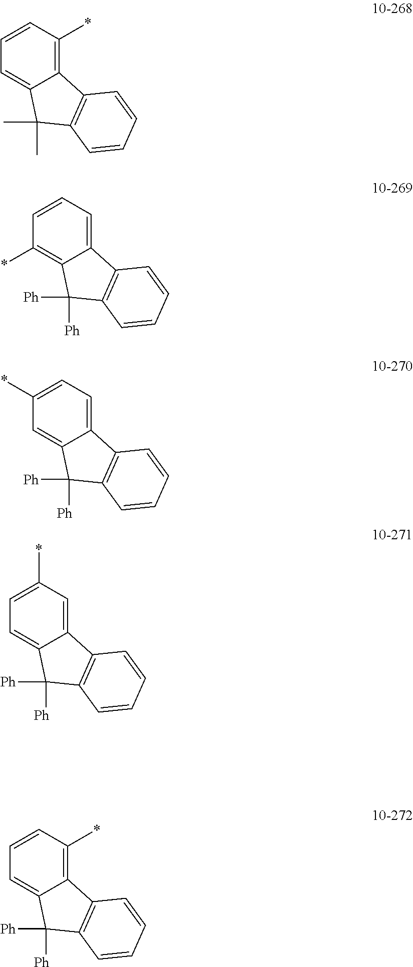 [SMILES: *c1cccc2c1-c1ccccc1C2(C)C ; *c1cccc2c1C(c1ccccc1)(c1ccccc1)c1ccccc1-2 ; *c1ccc2c(c1)C(c1ccccc1)(c1ccccc1)c1ccccc1-2 ; *c1ccc2c(c1)-c1ccccc1C2(c1ccccc1)c1ccccc1 ; *c1cccc2c1-c1ccccc1C2(c1ccccc1)c1ccccc1]

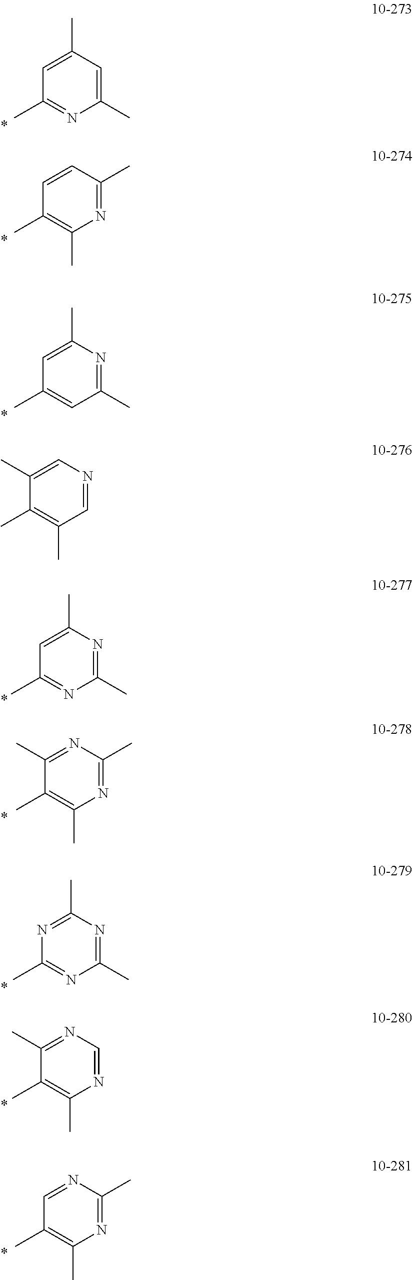

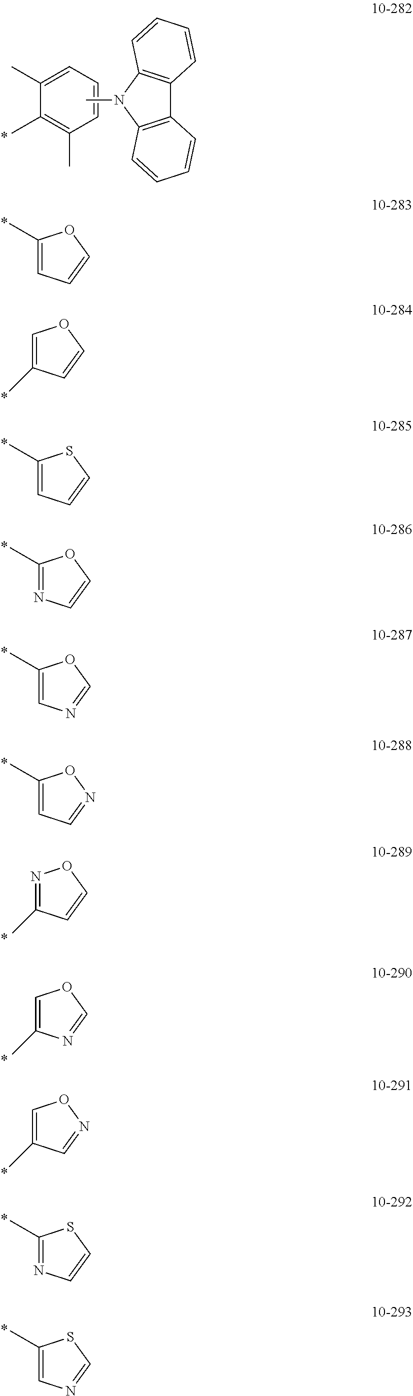

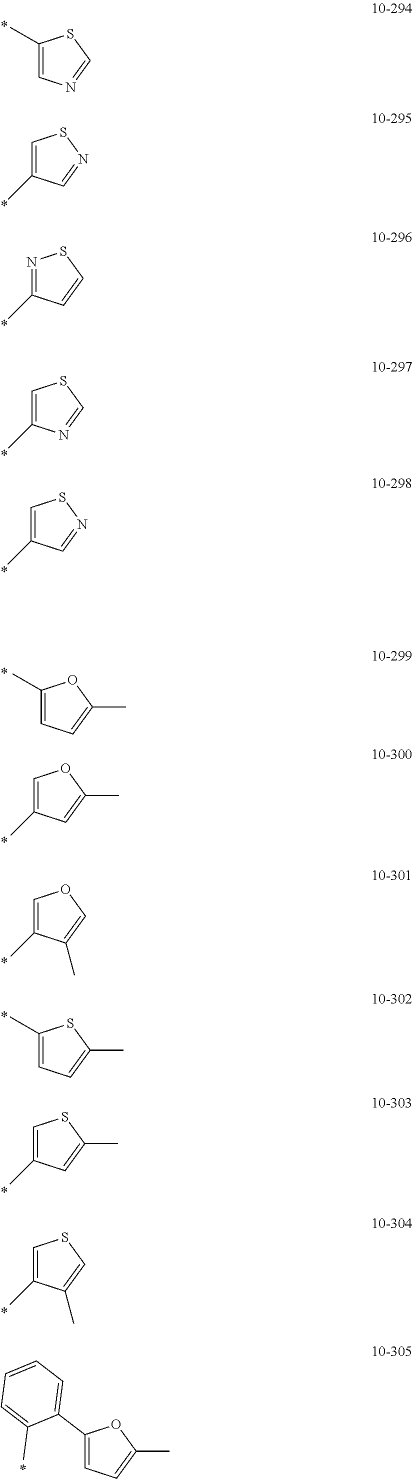

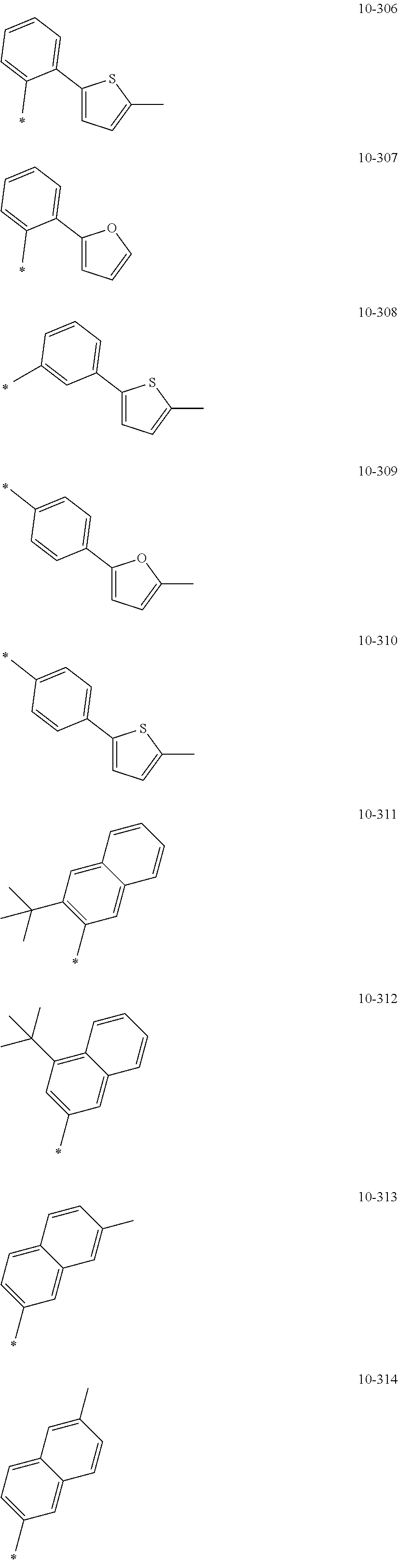

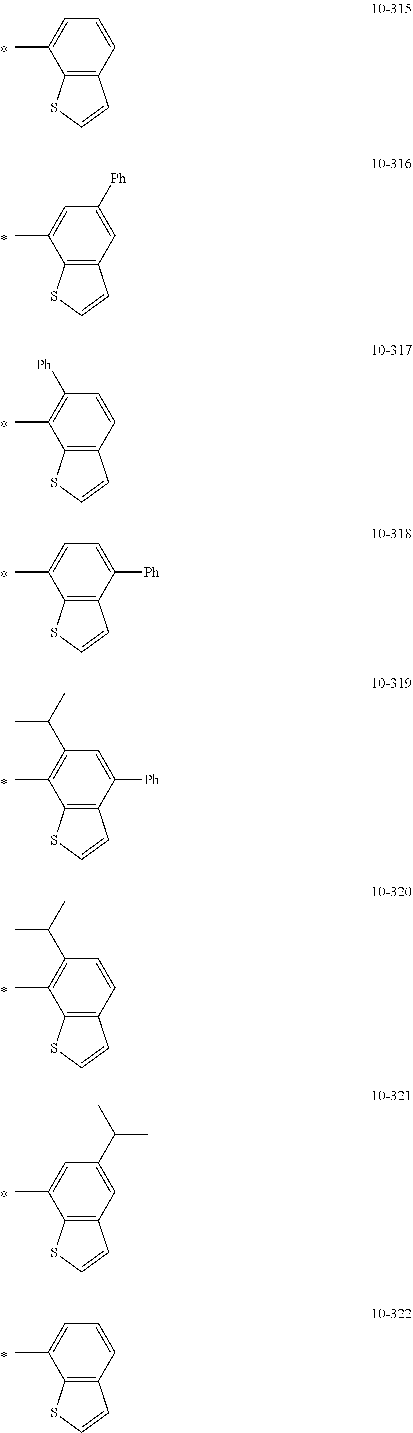

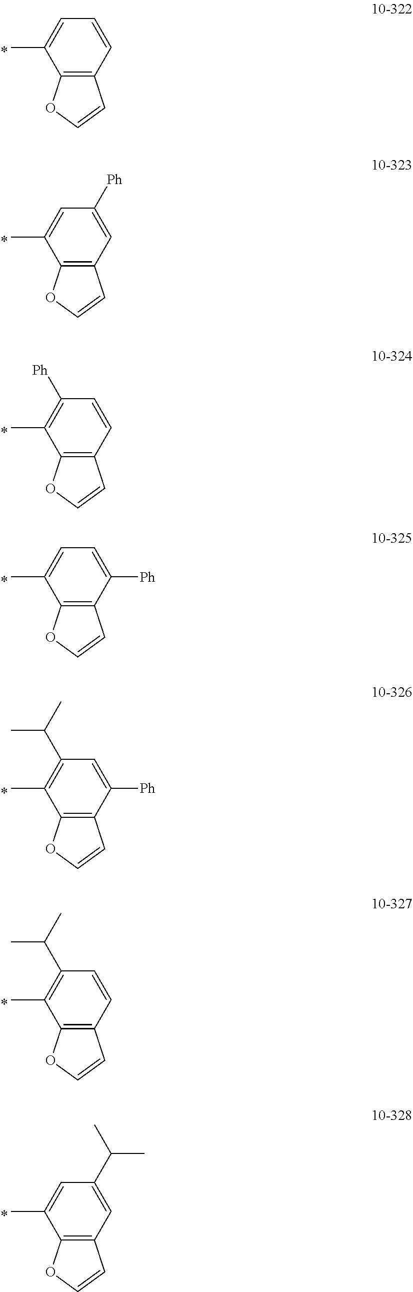

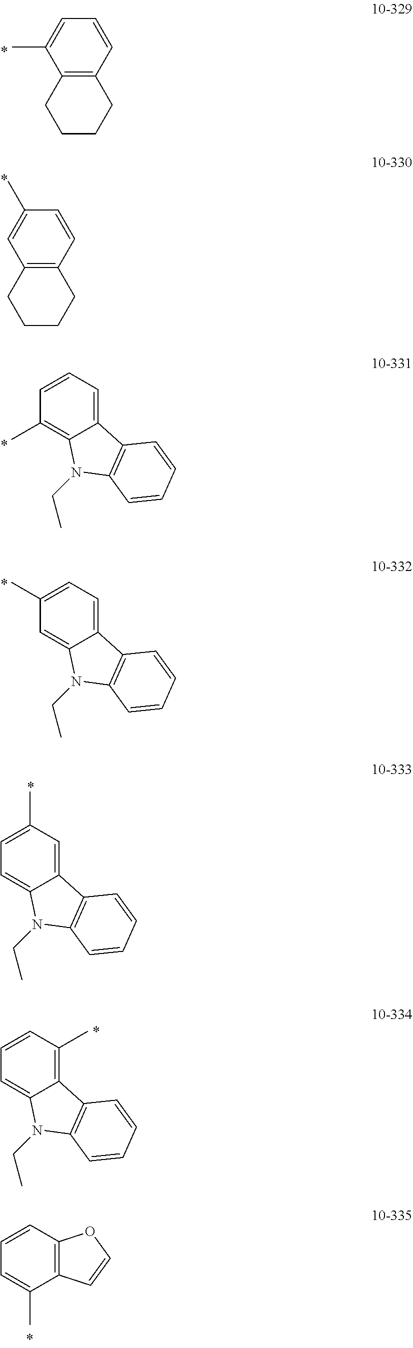

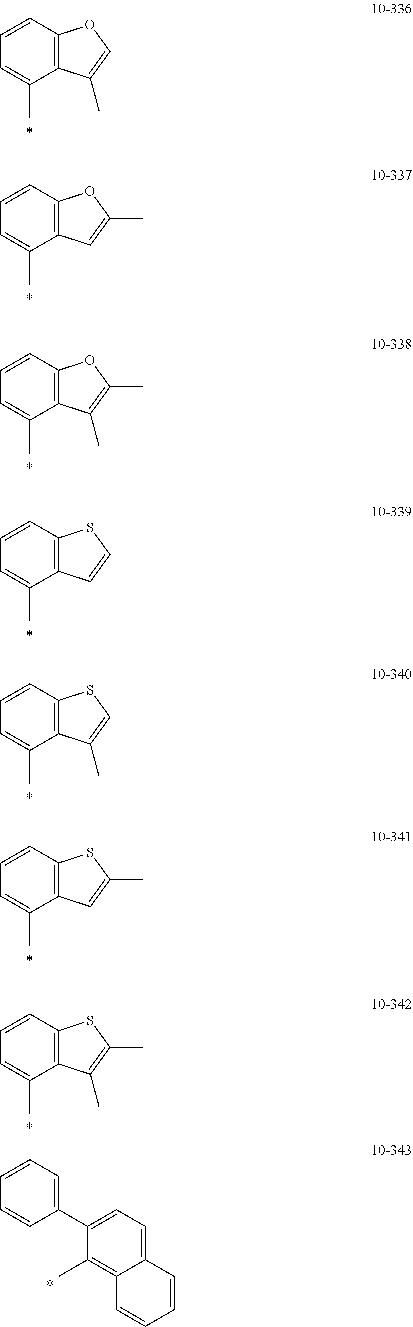

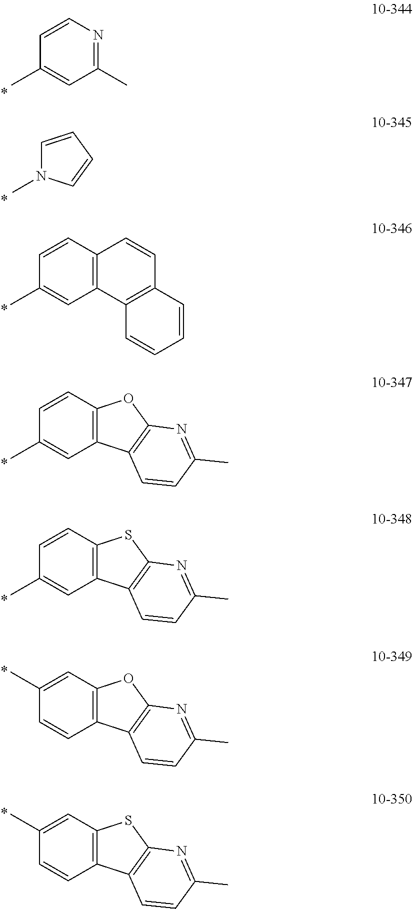

In Formulae 9-1 to 9-39, 9-201 to 9-237, 10-1 to 10-129, and 10-201 to 10-350, * indicates a binding site to a neighboring atom, “Ph” is a phenyl group, “TMS” is a trimethylsilyl group, and “TMG” is a trimethylgermyl group.

The “group represented by one of Formulae 9-1 to 9-39 in which at least one hydrogen is substituted with deuterium” and the “group represented by one of Formulae 9-201 to 9-227 in which at least one hydrogen is substituted with deuterium” may each be, for example, a group represented by one of Formulae 9-501 to 9-514 and 9-601 to 9-636:

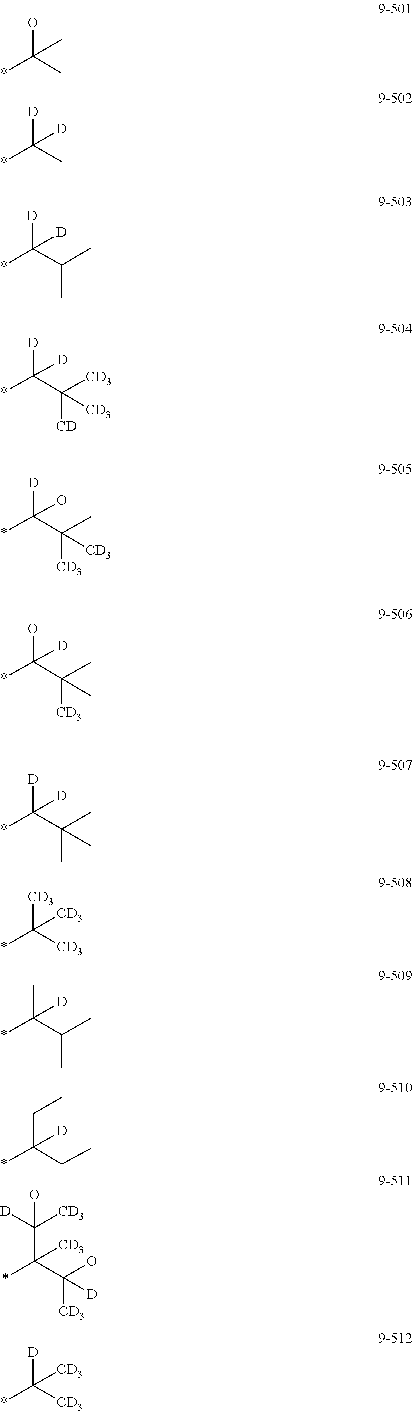

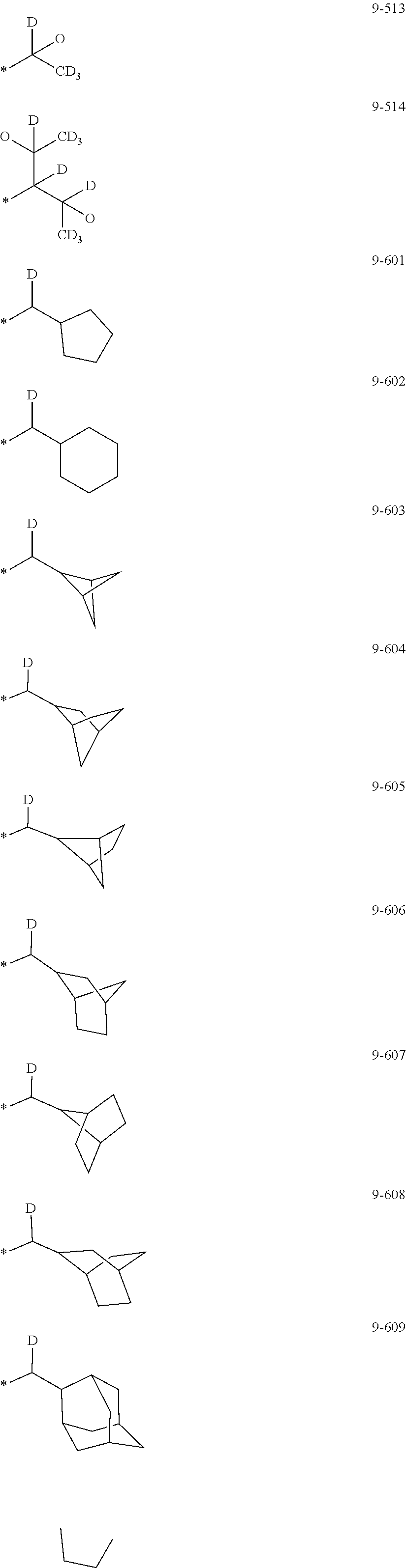

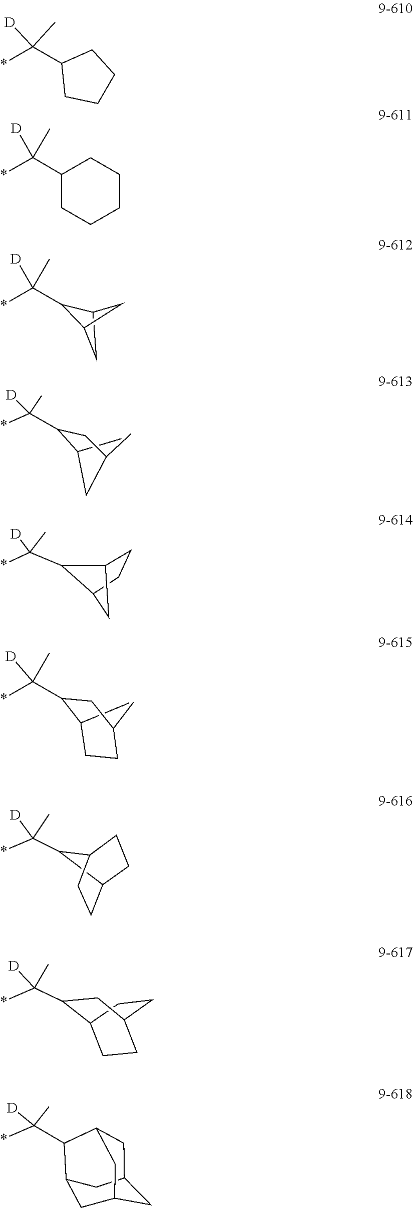

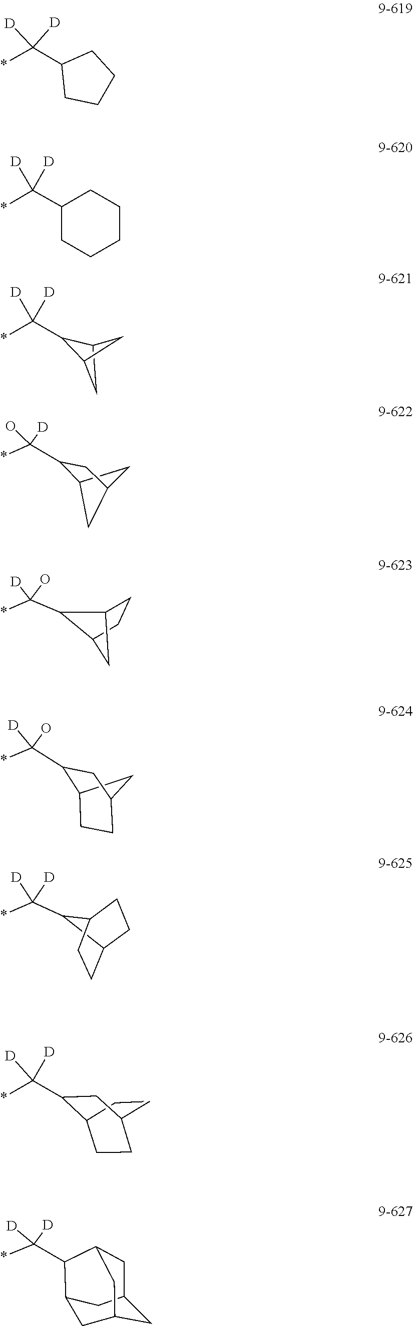

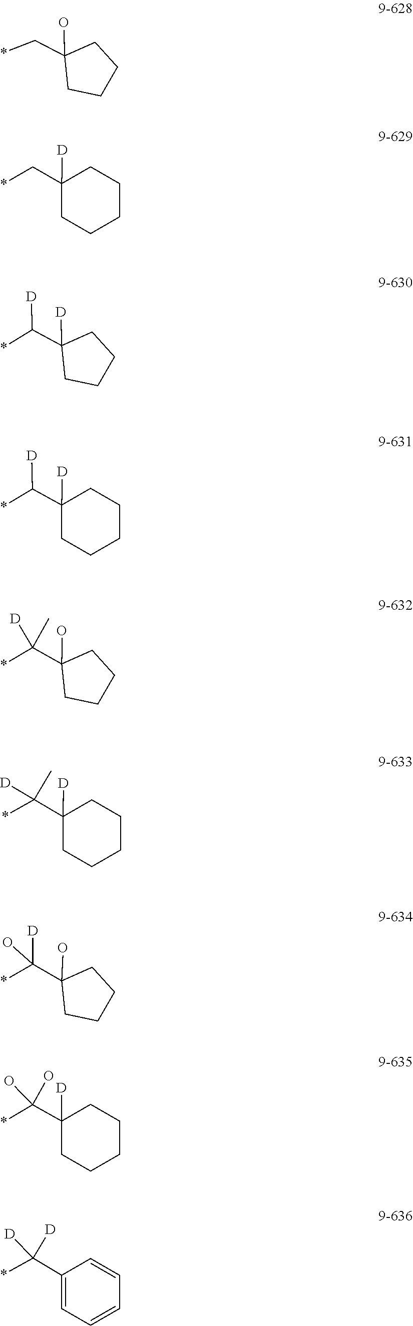

The “group represented by one of Formulae 9-1 to 9-39 in which at least one hydrogen is substituted with —F” and the “group represented by one of Formulae 9-201 to 9-227 in which at least one hydrogen is substituted with —F” may each be, for example, a group represented by one of Formulae 9-701 to 9-710:

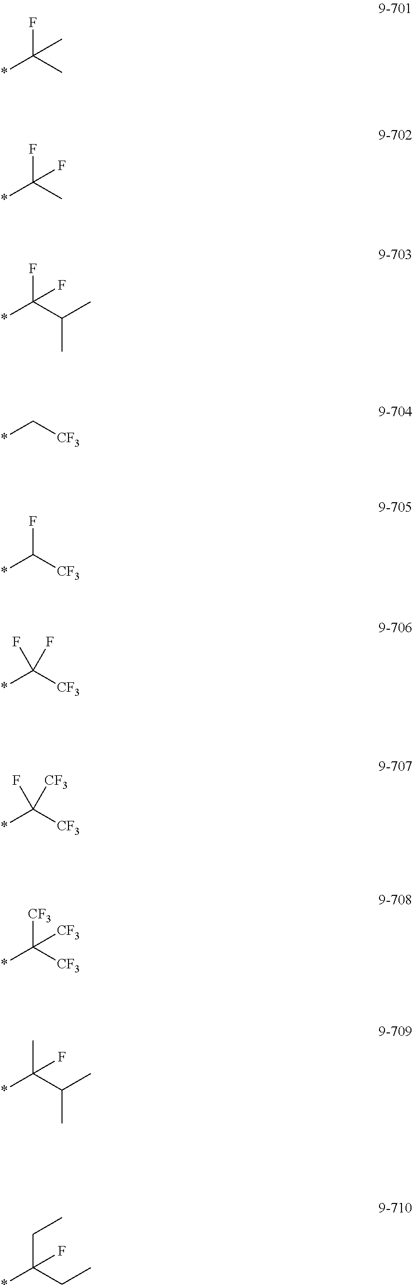

The “group in which at least one hydrogen in Formulae 10-1 to 10-129 is substituted with deuterium” and “the group in which at least one hydrogen in Formulae 10-201 to 10-350 is substituted with deuterium” may be, for example, a group represented by one of Formulae 10-501 to 10-553:

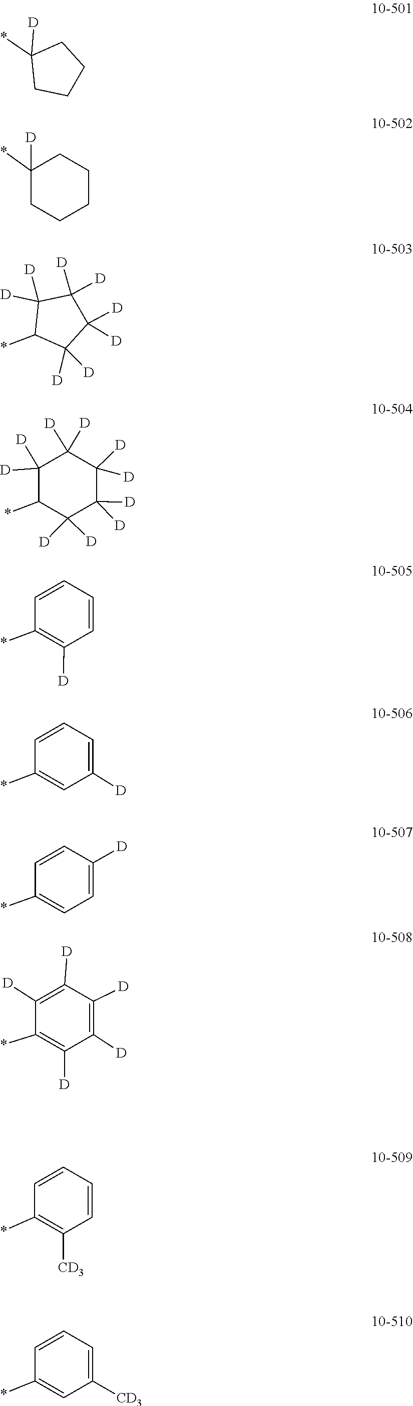

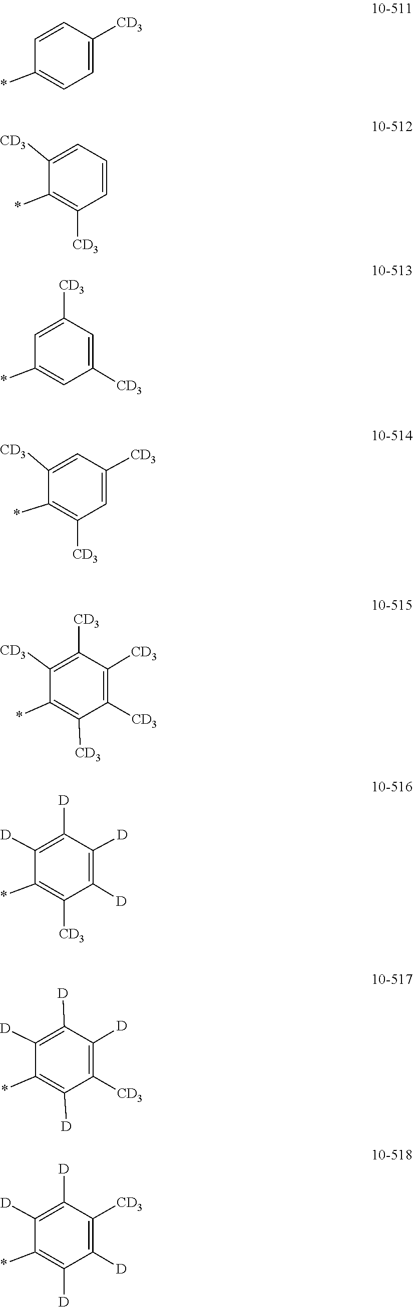

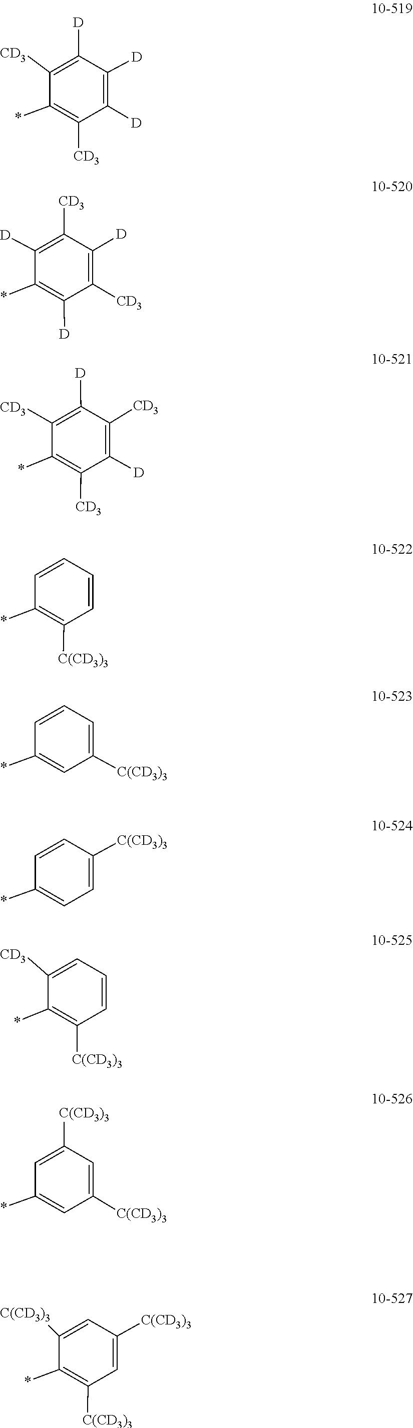

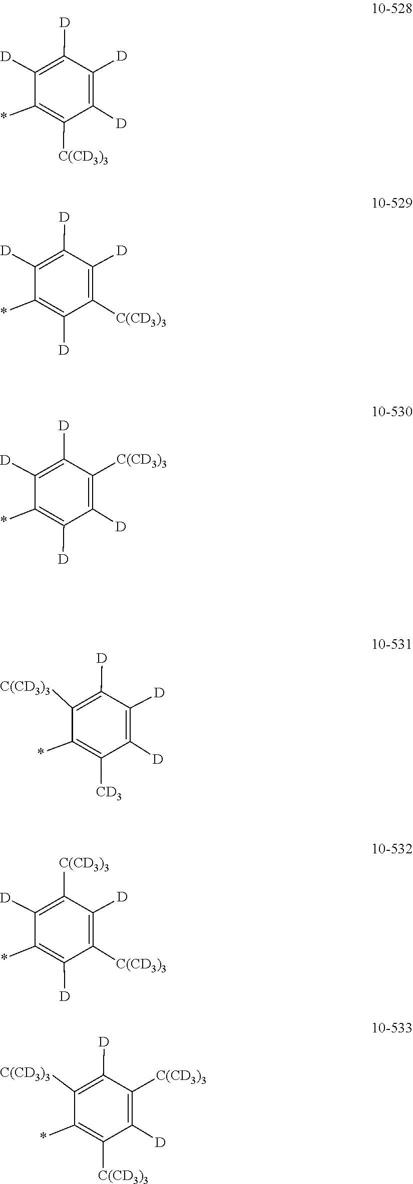

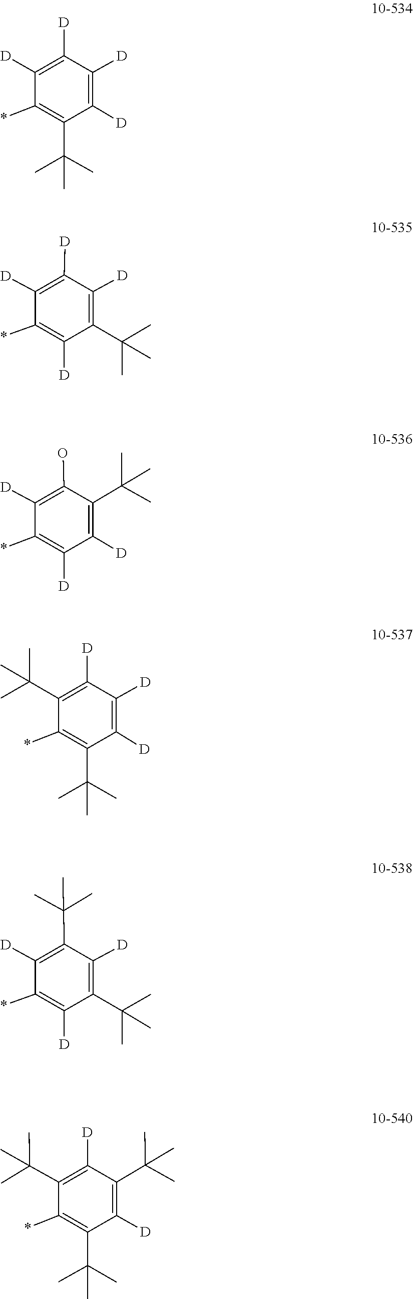

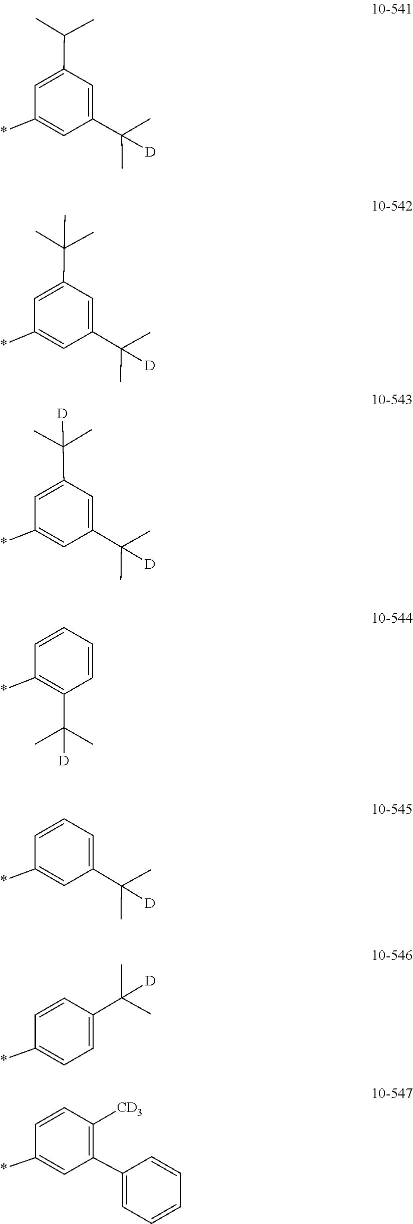

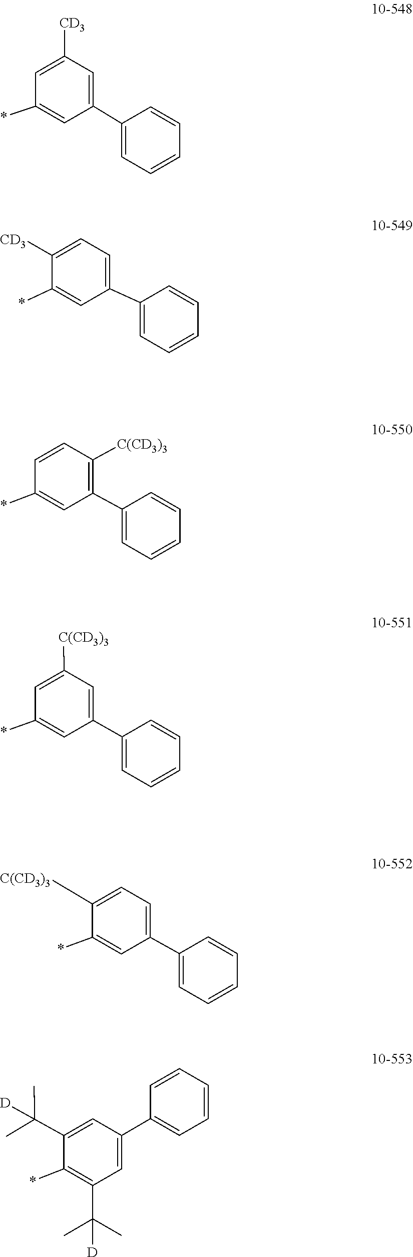

The “group in which at least one hydrogen in Formulae 10-1 to 10-129 is substituted with —F” and “the group in which at least one hydrogen in Formulae 10-201 to 10-350 is substituted with —F” may be, for example, a group represented by one of Formulae 10-601 to 10-617:

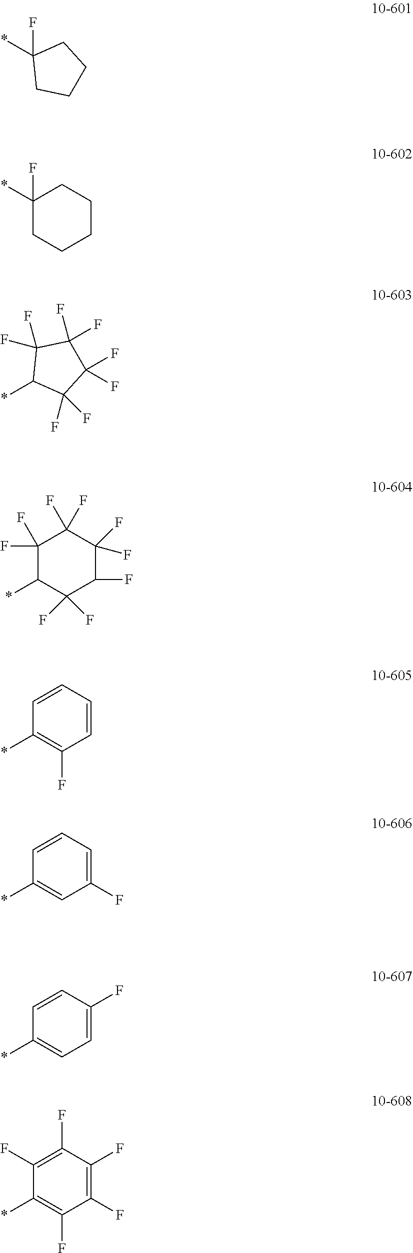

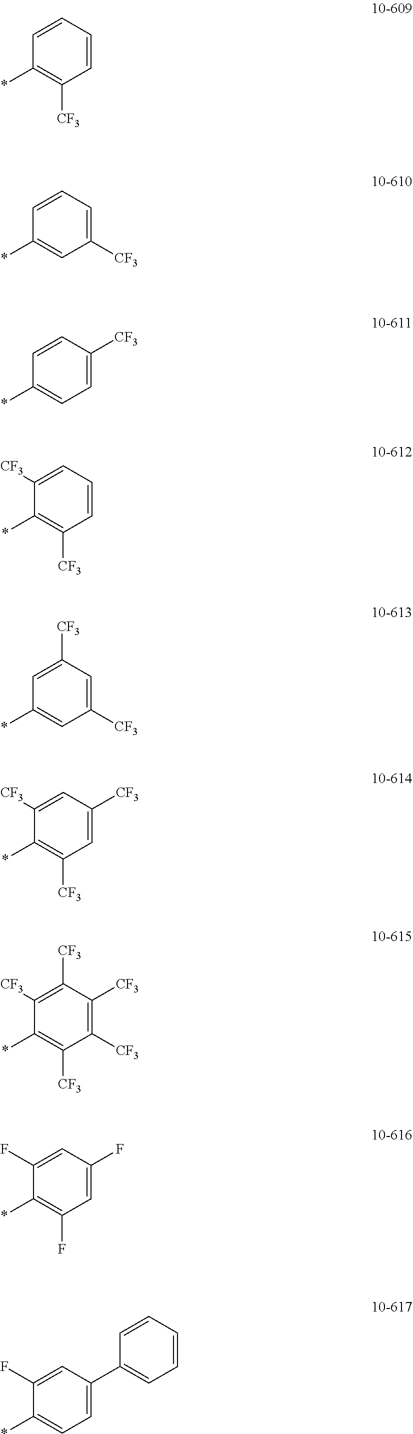

In Formulae 1, 2-1, and 2-2, c1 to c4 indicate the number of R₁(s) to the number of R₄(s), respectively; a1 to a4 indicate the number of groups represented by *-[(L₁)_{b1}-(R₁)_{c1}], the number of groups represented by *-[(L₂)_{b2}-(R₂)_{c2}], the number of groups represented by *-[(L₃)_{b3}-(R₃)_{c3}], and the number of groups represented by *-[(L₄)_{b4}-(R₄)_{c4}], respectively; e1 to e4 indicate the number of Z₁(s) to the number of Z₄(s), respectively; and d1 to d4 indicate the number of a group(s) represented by *—[W₁—(Z₁)ₑ₁], the number of groups represented by *—[W₂—(Z₂)ₑ₂], the number of groups represented by *—[W₃—(Z₃)ₑ₃], and the number of groups represented by *—[W₄—(Z₄)ₑ₄], respectively, and c1 to c4, a1 to a4, e1 to e4, and d1 to d4 may each independently be an integer from 0 to 20. When c1 is 2 or more, two or more R₁(s) may be identical to or different from each other, when c2 is 2 or more, two or more R₂(s) may be identical to or different from each other, when c3 is 2 or more, two or more R₃(s) may be identical to or different from each other, when c4 is 2 or more, two or more R₄(s) may be identical to or different from each other, when a1 is 2 or more, two or more groups represented by *-[(L₁)_{b1}-(R₁)_{c1}] may be identical to or different from each other, when a2 is 2 or more, two or more groups represented by *-[(L₂)_{b2}-(R₂)_{c2}] may be identical to or different from each other, when a3 is 2 or more, two or more groups represented by *-[(L₃)_{b3}-(R₃)_{c3}] may be identical to or different from each other, when a4 is 2 or more, two or more groups represented by *-[(L₄)_{b4}-(R₁)_{c4}] may be identical to or different from each other, when e1 is 2 or more, two or more Z₁(s) may be identical to or different from each other, when e2 is 2 or more, two or more Z₂(s) may be identical to or different from each other, when e3 is 2 or more, two or more Z₃(s) may be identical to or different from each other, when e4 is 2 or more, two or more Z₄(s) may be identical to or different from each other, when d1 is 2 or more, two or more groups represented by *—[W₁—(Z₁)ₑ₁] may be identical to or different from each other, when d2 is 2 or more, two or more groups represented by *—[W₂—(Z₂)ₑ₂] may be identical to or different from each other, when d3 is 2 or more, two or more groups represented by *—[W₃—(Z₃)ₑ₃] may be identical to or different from each other, and when d4 is 2 or more, two or more groups represented by *—[W₄—(Z₄)ₑ₁] may be identical to or different from each other. For example, in Formulae 1, 2-1, and 2-2, c1 to c4, a1 to a4, e1 to e4, and d1 to d4 may each independently be 0, 1, 2, or 3.

In one or more embodiments, in Formula 2-1, a case where Y₁ is N, ring A₁ is a pyridine group, Y₂ is C, ring A₂ is a benzene group, and each of d1 and d2 is 0 may be excluded.

In Formulae 1, 2-1, and 2-2, two or more substituents in at least one of i) two or more of a plurality of R₁(s), ii) two or more of a plurality of R₂(s), iii) two or more of a plurality of R₃(s), iv) two or more of a plurality of R₄(s), v) R₅ₐ and R_{5b}, vi) two or more of a plurality of Z₁(s), vii) two or more of a plurality of Z₂(s), viii) two or more of a plurality of Z₃(s), ix) two or more of a plurality of Z₄(s), x) two or more of R₁ to R₄, R₅ₐ, and R_{5b}, and xi) two or more of Z₁ to Z₄ may optionally be linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ.

R₁₀ₐ may be as described in connection with R₁.

The symbols * and *′ as used herein each indicate a binding site to a neighboring atom, unless otherwise stated.

In one or more embodiments, in Formula 1, n1 may not be 0, n4 may be 0, and a group represented by

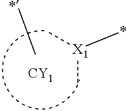

may be a group represented by one of Formulae CY1(1) to CY1(23):

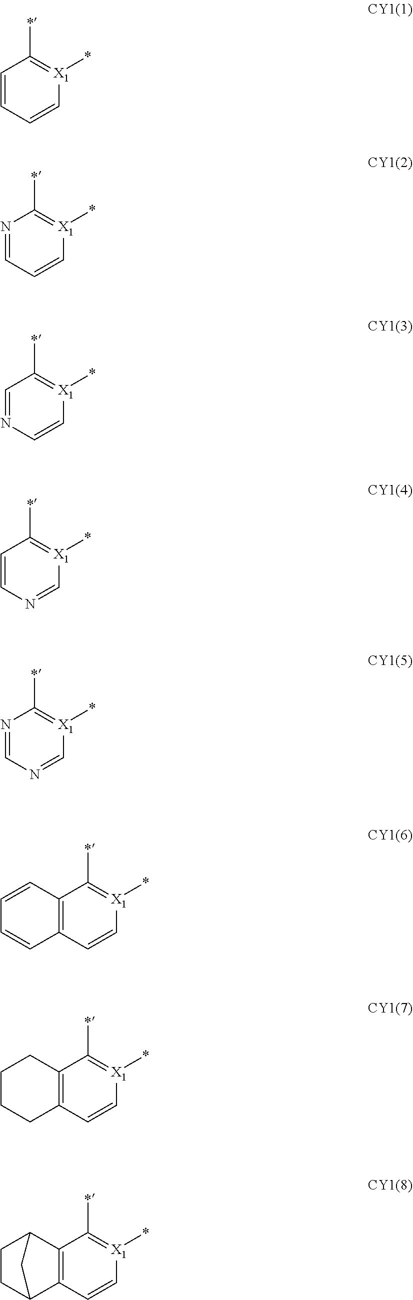

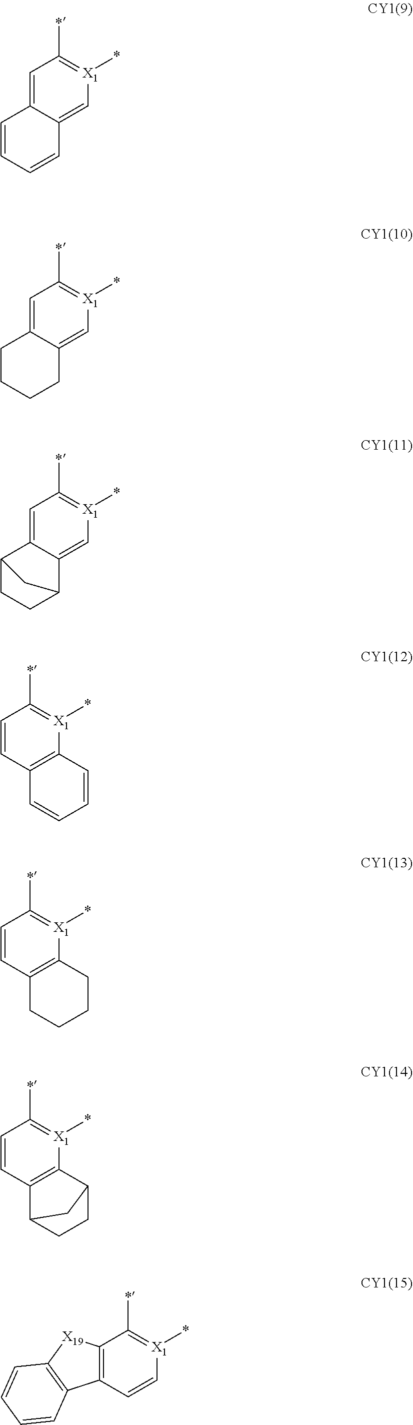

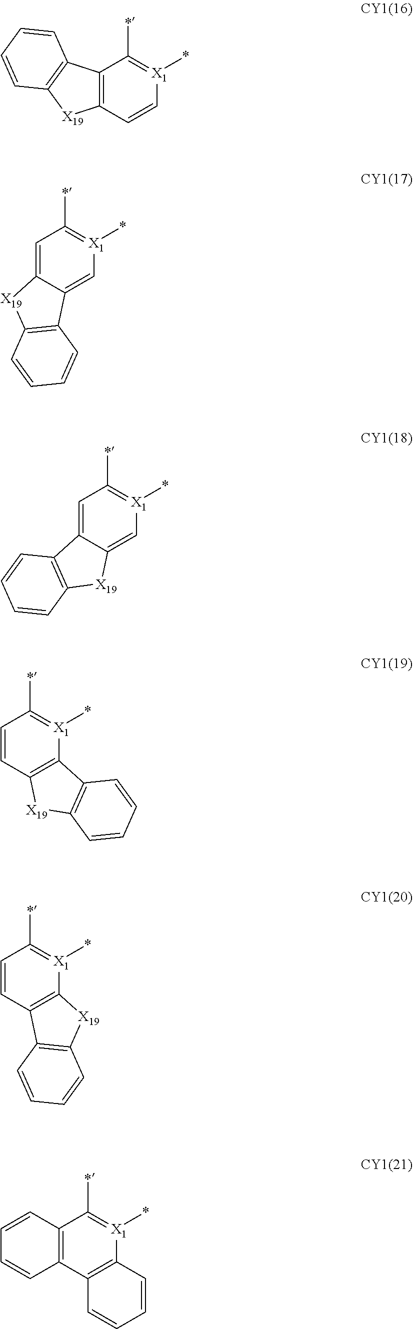

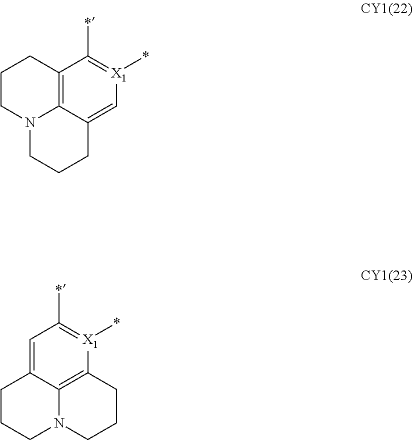

wherein, in Formulae CY1(1) to CY1(23),

X₁ is as described above,

X₁₉ may be *—O—*′, *—S—*′, *—Se—*′, *—N(R₁₉ₐ)—*′, *—C(R₁₉ₐ)(R_{19b})—*′, or *—Si(R₁₉ₐ)(R_{19b})—*′

R₁₉ₐ and R_{19b} may each be as described in connection with R₁,

* indicates a binding site to X₅ in Formula 1, and

*′ indicates a binding site to T₁₁ in Formula 1.

In one or more embodiments, in Formula 1, n1 may be 1, n4 may be 0, and a group represented by

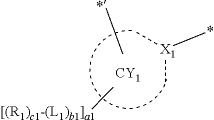

may be a group represented by one of Formulae CY1-1 to CY1-18:

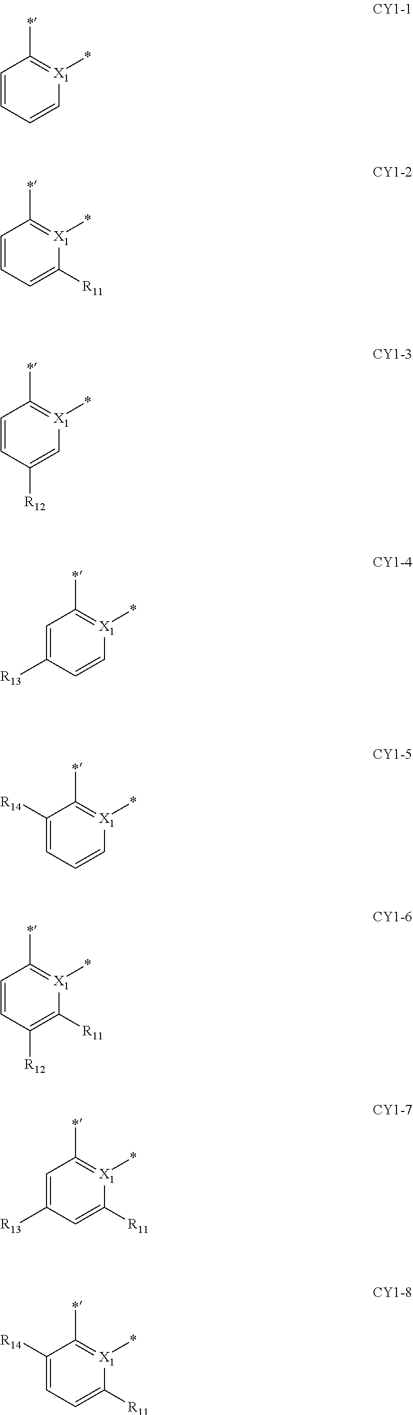

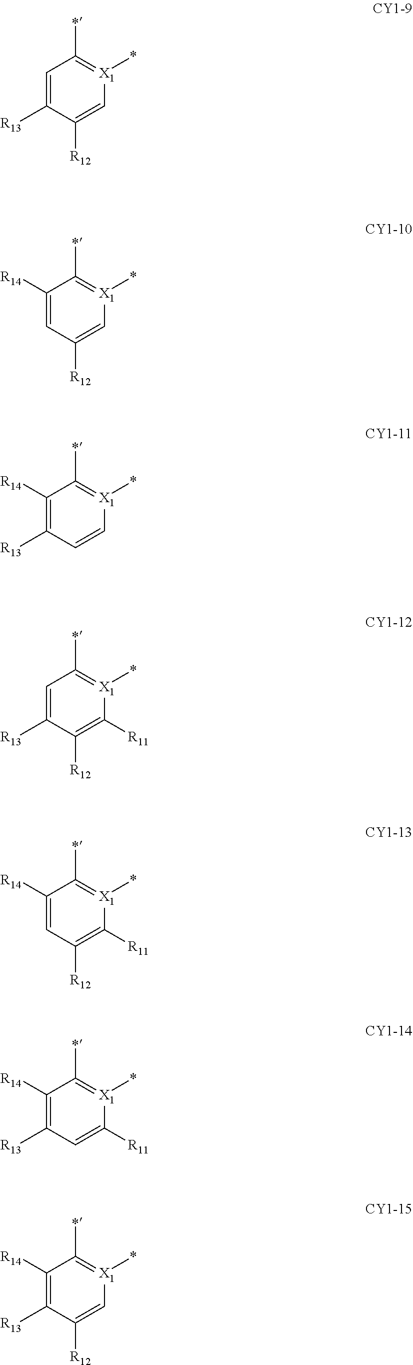

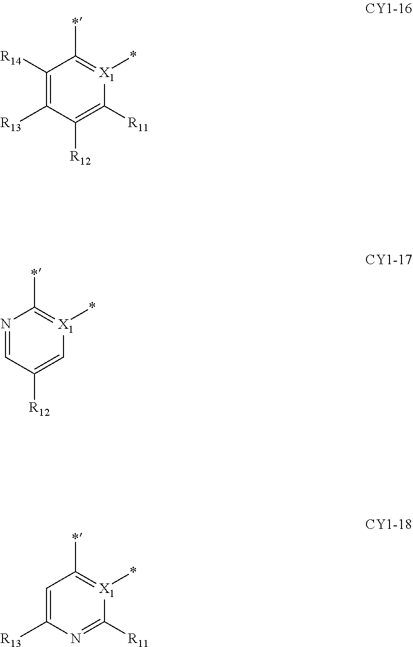

wherein, in Formulae CY1-1 to CY1-18,

X₁ is as described above,

R₁₁ to R₁₄ may each be the same as described in connection with R₁, and each of R₁₁ to R₁₄ may not be hydrogen,

* indicates a binding site to X₅ in Formula 1, and

*′ indicates a binding site to T₁₁ in Formula 1.

In one or more embodiments, in Formula 1, n1 and n2 may each be 1, and ring CY₂ may be a group represented by Formula CY2A or CY2B:

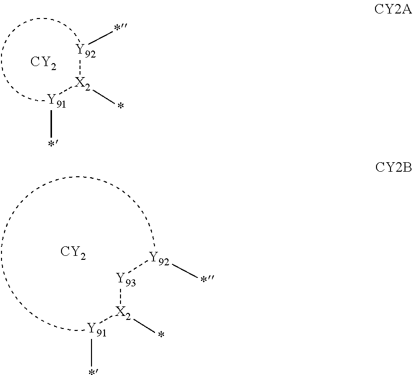

wherein, in Formulae CY2A and CY2B,

X₂ and CY₂ may each be as described herein,

Y₉₁ to Y₉₃ may each independently be *—O—*′, *—S—*′, *—N—*′, *—C—*′, or *—Si—*′,

in Formula CY2A, a bond between X₂ and Y₉₁, a bond between X₂ and Y₉₂, a bond between X₂ and Y₉₃, and a bond between Y₂₂ and Y₉₃ may each be a chemical bond,

*′ indicates a binding site to T₁₁ in Formula 1,

* indicates a binding site to M₁ in Formula 1, and

*″ indicates a binding site to T₁₂ in Formula 1.

In one or more embodiments, in Formula 1, each of n1 and n2 may not be 0, and a group represented by

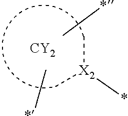

may be a group represented by one of Formulae CY2(1) to CY2(21):

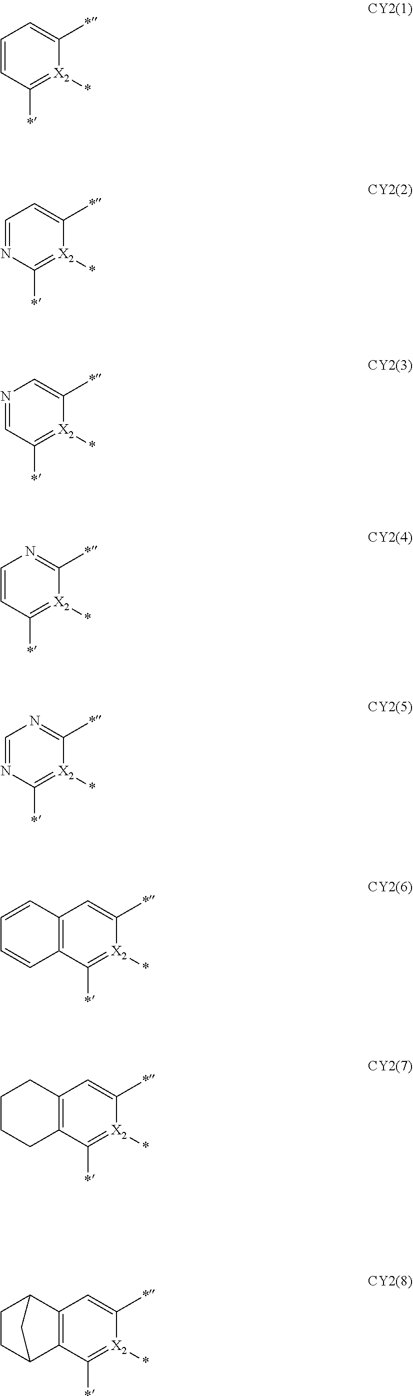

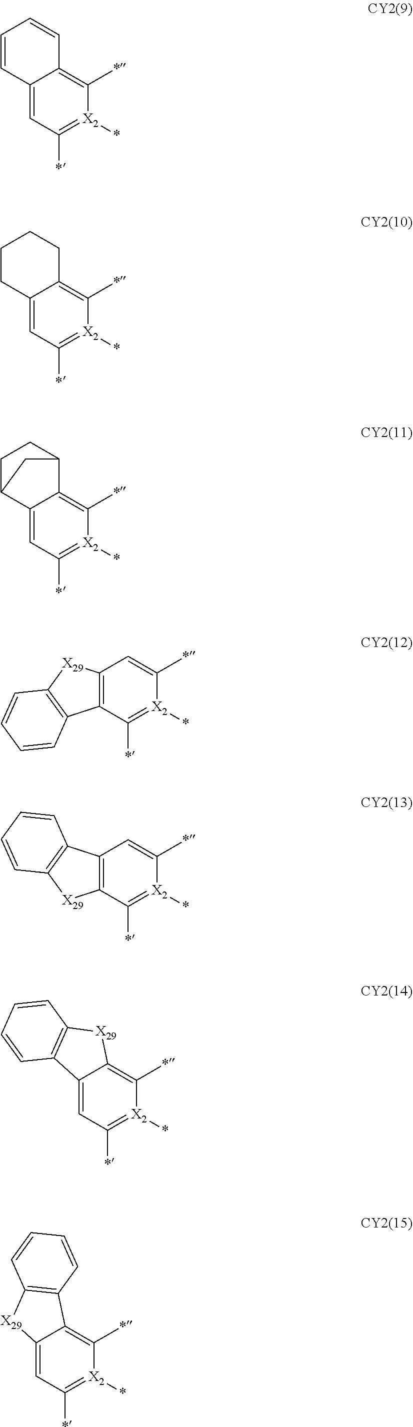

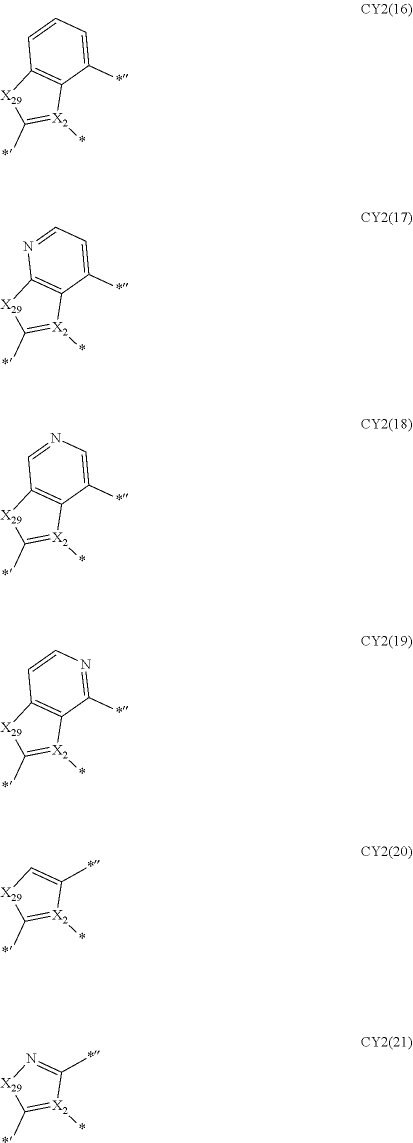

wherein, in Formulae CY2(1) to CY2(21),

X₂ is as described in the present specification,

X₂₉ may be O, S, N-[(L₂)_{b2}-(R₂)_{c2}], C(R₂₉ₐ)(R_{29b}), or Si(R₂₉ₐ)(R_{29b}),

L₂, b2, R₂, and c2 may each be the same as described herein,

R₂₉ₐ and R_{29b} may each be the same as described in connection with R₂,

*′ indicates a binding site to T₁₁ in Formula 1,

* indicates a binding site to M₁ in Formula 1,

*″ indicates a binding site to T₁₂ in Formula 1.

In one or more embodiments, in Formula 1, each of n1 and n2 may be 1, and a group represented by

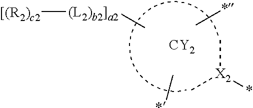

may be a group represented by one of Formulae CY2-1 to CY2-16:

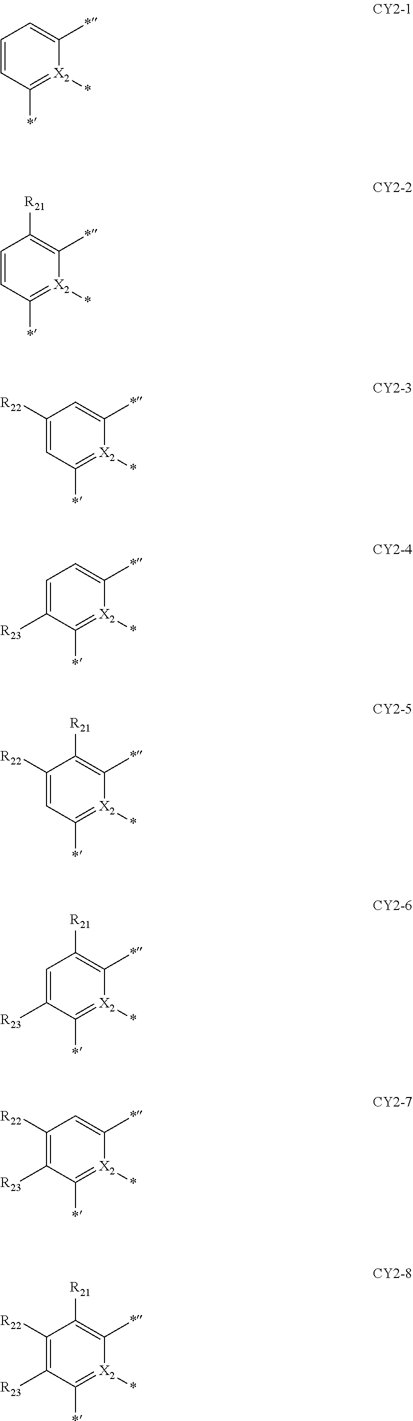

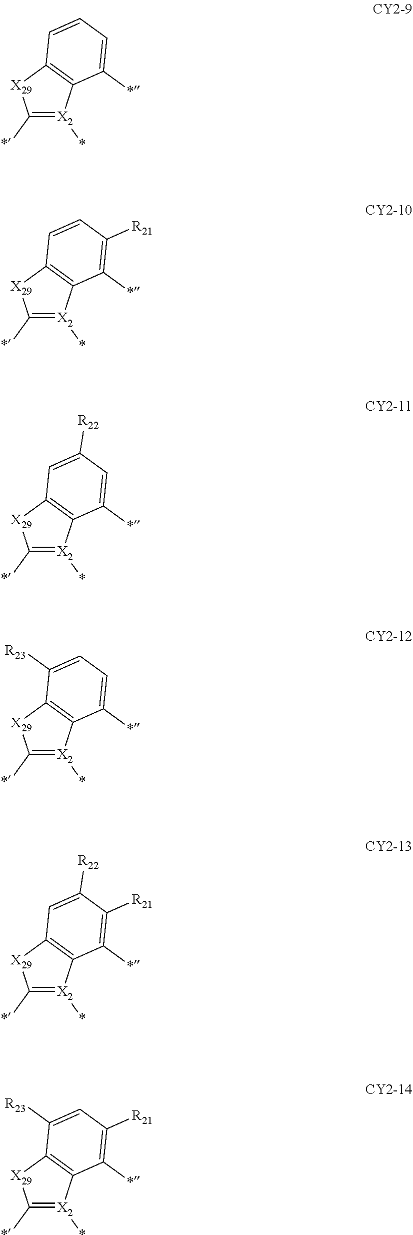

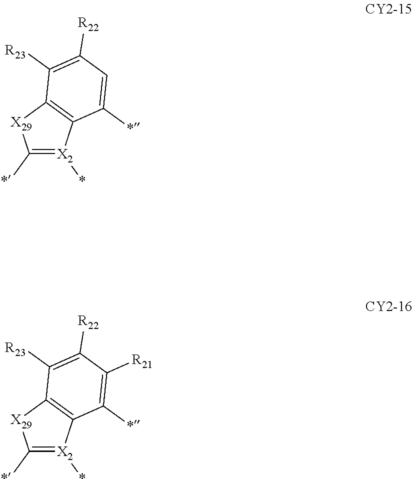

wherein, in Formulae CY2-1 to CY2-16,

X₂ is the same as described in the present specification,

X₂₉ may be O, S, N-[(L₂)_{b2}-(R₂)_{c2}], C(R₂₉ₐ)(R_{29b}), or Si(R₂₉ₐ)(R_{29b}),

L₂, b2, R₂, and c2 may each be the same as described herein,

R₂₁ to R₂₃, R₂₉ₐ, and R_{29b} may each be the same as described in connection with R₂, wherein each of R₂₁ to R₂₃ may not be hydrogen,

*′ indicates a binding site to T₁ in Formula 1,

* indicates a binding site to M₁ in Formula 1,

*″ indicates a binding site to T₁₂ in Formula 1.

In one or more embodiments, in Formula 1,

each of n1 and n2 may be 1,

a group represented by

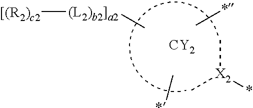

may be represented by one of Formulae CY2-9 to CY2-16,

X₂₉ in Formulae CY2-9 to CY2-16 may be N-[(L₂)_{b2}-(R₂)_{c2}],

L₂ may be a benzene group unsubstituted or substituted with at least one R₁₀ₐ,

b2 may be 1 or 2,

c2 may be 2, and

a) one of two R₂(s) may be a phenyl group unsubstituted or substituted with at least one of deuterium, a C₁-C₂₀ alkyl group, a phenyl group, a deuterated phenyl group, a (C₁-C₂₀ alkyl)phenyl group, or a combination thereof, and b) the other R₂ may be a C₄-C₂₀alkyl group or a deuterated C₁-C₂₀ alkyl group, each unsubstituted or substituted with at least one C₃-C₁₀ cycloalkyl group.

In one or more embodiments, in Formula 1, each of n2 and n3 may not be 0, and a group represented by

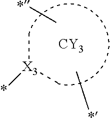

may be a group represented by one of Formulae CY3(1) to CY3(15):

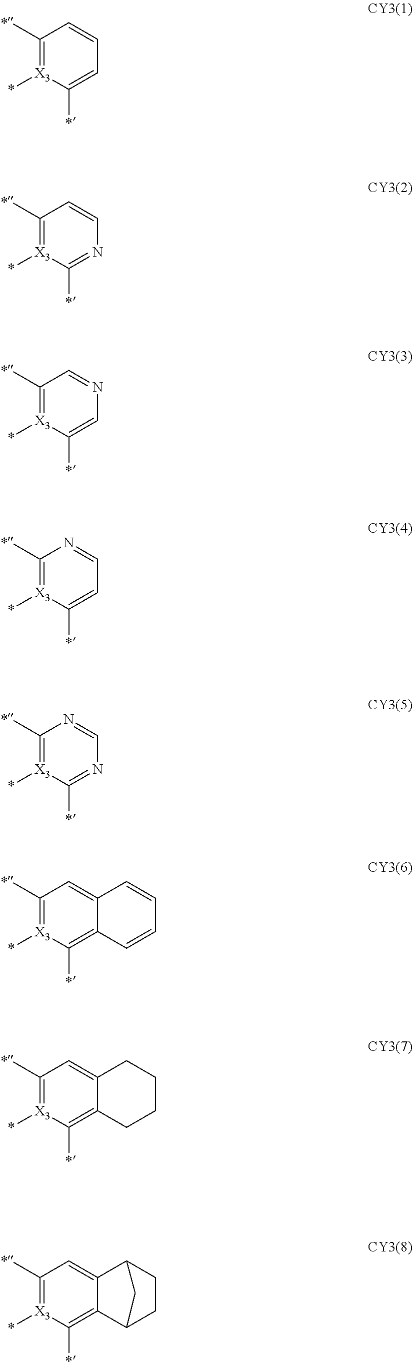

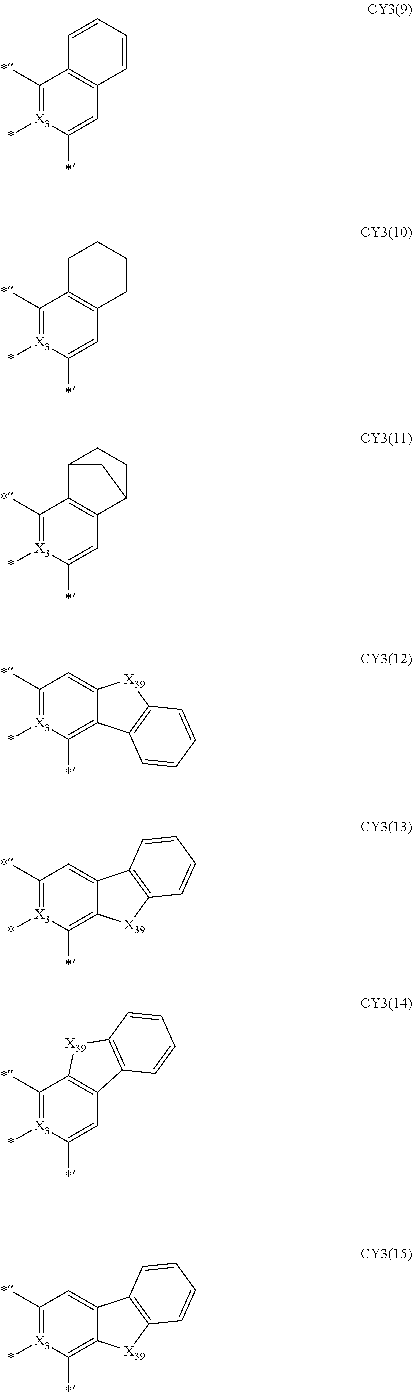

wherein, in Formulae CY3(1) to CY3(15),

X₃ is the same as described in the present specification,

X₃₉ may be O, S, N(Z₃₉ₐ), C(R₃₉ₐ)(R_{39b}), or Si(R₃₉ₐ)(R_{39b}),

R₃₉ₐ and R_{39b} may each be the same as described in connection with R₃,

*″ indicates a binding site to T₁₂ in Formula 1,

* indicates a binding site to M₁ in Formula 1,

* indicates a binding site to T₁₃ in Formula 1.

In one or more embodiments, in Formula 1, each of n2 and n3 may be 1, and a group represented by

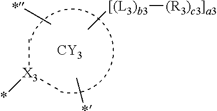

may be a group represented by one of Formulae CY3-1 to CY3-13:

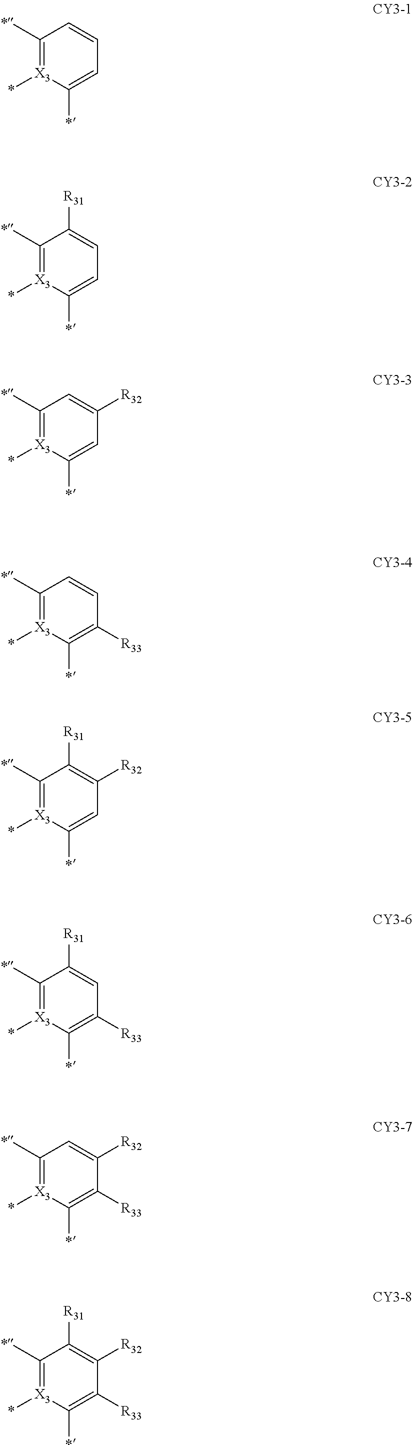

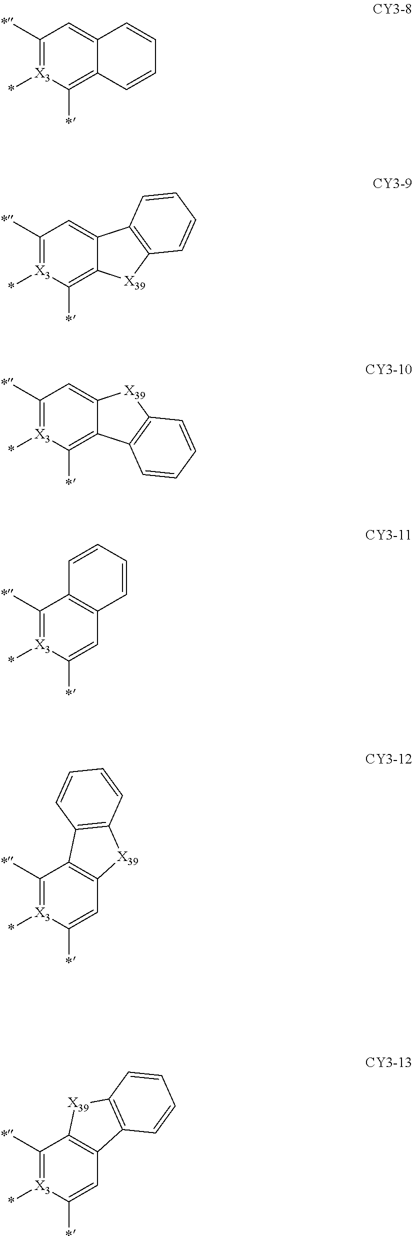

wherein, in Formulae CY3-1 to CY3-31,

X₃ is the same as described in the present specification,

X₃₉ may be O, S, N-[(L₃)_{b3}-(R₃)_{c3}], C(R₃₉ₐ)(R_{39b}), or Si(R₃₉ₐ)(R_{39b}),

L₃, b3, R₃, and c3 may each be the same as described herein,

R₃₁ to R₃₃, R₃₉ₐ, and R_{39b} may each be the same as described in connection with R₃, wherein each of R₃₁ to R₃₃ may not be hydrogen,

*″ indicates a binding site to T₁₂ in Formula 1,

* indicates a binding site to M₁ in Formula 1,

*′ indicates a binding site to T₁₃ in Formula 1.

In one or more embodiments, in Formula 1, n3 may not be 0, n4 may be 0, and a group represented by

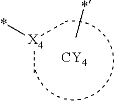

may be a group represented by one of Formulae CY4(1) to CY4(20):

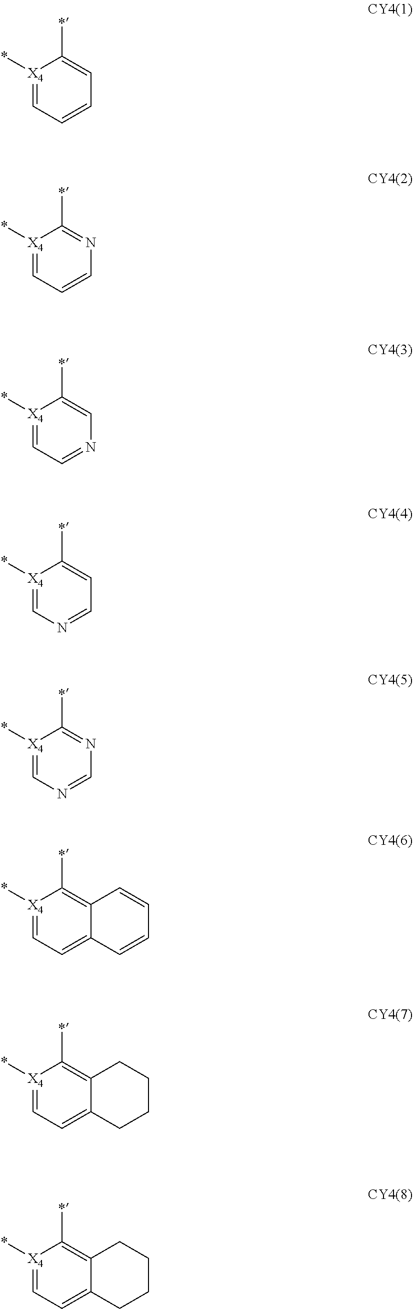

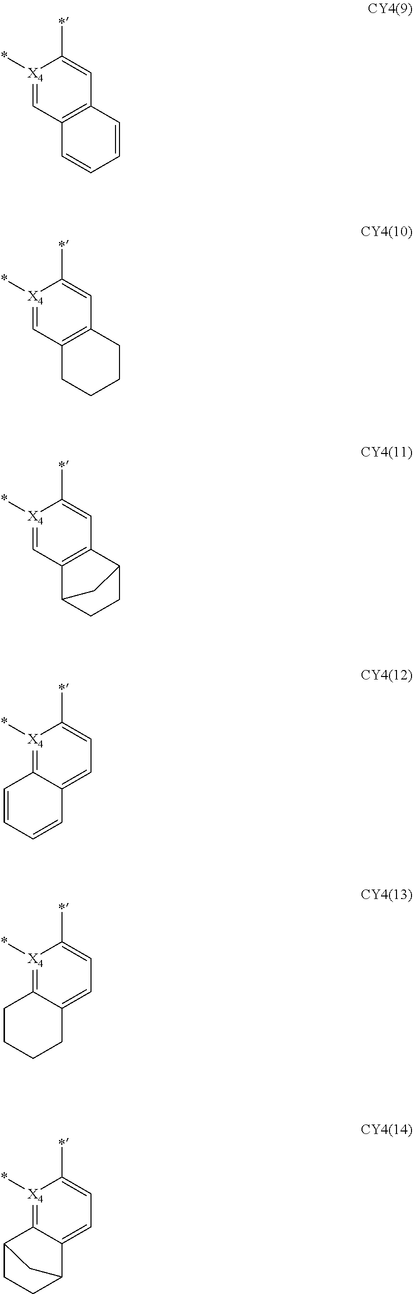

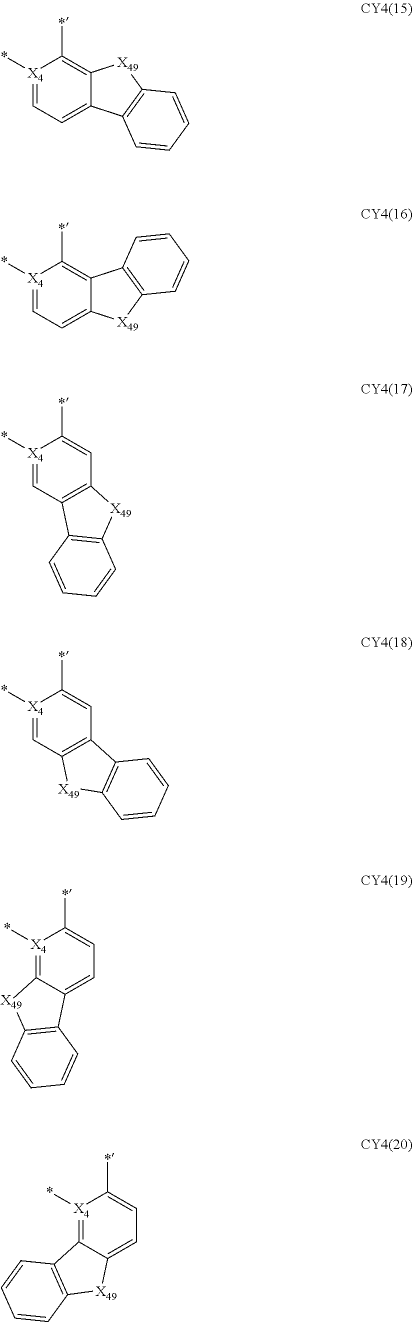

wherein, in Formulae CY4(1) to CY4(20),

X₄ is the same as described in the present specification,

X₄₉ may be O, S, N(R₄₉ₐ), C(R₄₉ₐ)(R_{49b}), or Si(R₄₉ₐ)(R_{49b}),

R₄₉ₐ and R_{49b} may each be the same as described in connection with R₄,

*′ indicates a binding site to T₁₃ in Formula 1, and

* indicates a binding site to M₁ in Formula 1.

In one or more embodiments, in Formula 1, n3 may be 1, n4 may be 0, and a group represented by

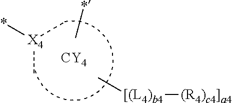

may be a group represented by one of Formulae CY4-1 to CY4-16:

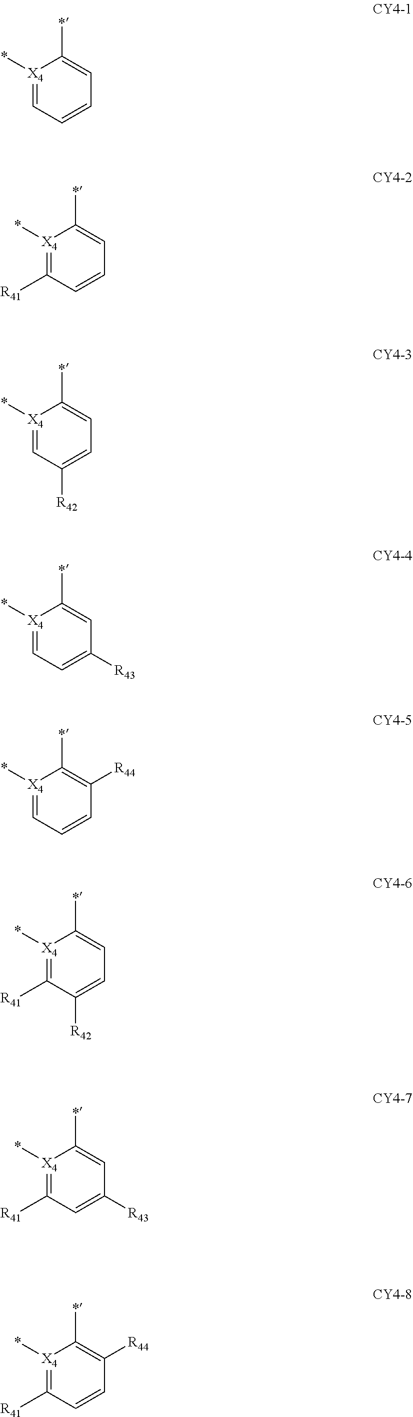

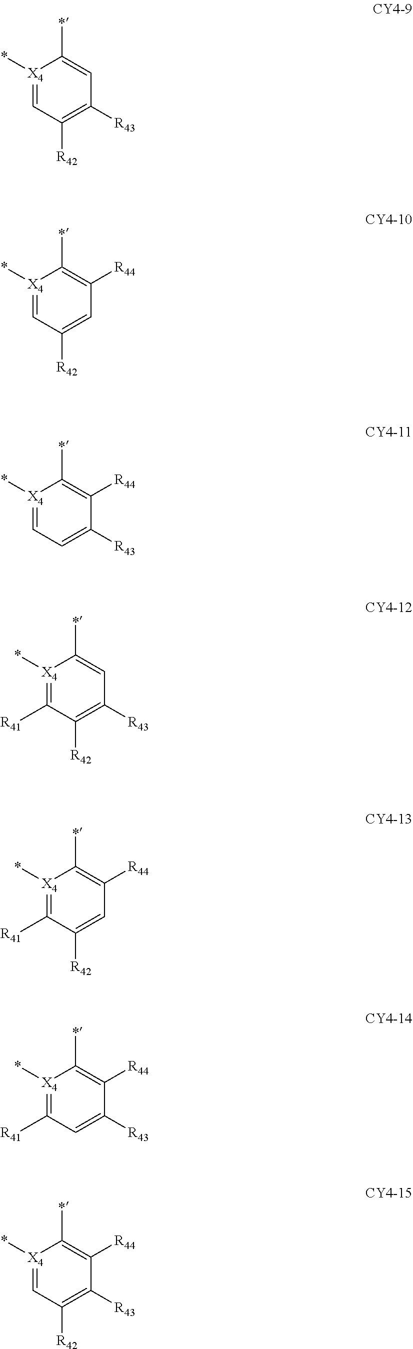

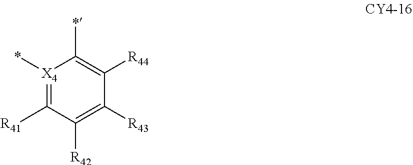

wherein, in Formulae CY4-1 to CY4-16,

X₄ is the same as described in the present specification,

R₄₁ to R₄₄ may each be the same as described in connection with R₄, and each of R₄₁ to R₄₄ may not be hydrogen,

*′ indicates a binding site to T₁₃ in Formula 1, and

* indicates a binding site to M₁ in Formula 1.

In one or more embodiments, the platinum-containing organometallic compound may be a compound represented by one of Formulae 1-1 to 1-3:

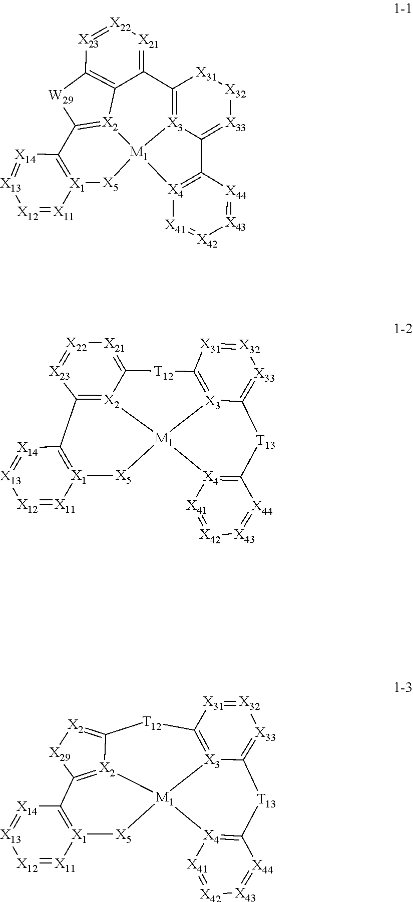

wherein, in Formulae 1-1 to 1-3,

M₁, X₁ to X₅, T₁₂, and T₁₃ may each be the same as described herein,

X₁₁ may be N or C(R₁₁), X₁₂ may be N or C(R₁₂), X₁₃ may be N or C(R₁₃), and X₁₄ may be N or C(R₁₄),

R₁₁ to R₁₄ may each be the same as described in connection with R₁,

two or more of Ru to R₁₄ may optionally be linked to each other to form a C₅-C₃₀ carbocyclic group unsubstituted or substituted with at least one R₁₀ₐ, or a C₁-C₃₀ heterocyclic group unsubstituted or substituted with at least one R₁₀ₐ,

X₂₁ may be N or C(R₂₁), X₂₂ may be N or C(R₂₂), and X₂₃ may be N or C(R₂₃),

X₂₉ may be O, S, N-[(L₂)_{b2}-(R₂)_{c2}], C(R₂₉ₐ)(R_{29b}), or Si(R₂₉ₐ)(R_{29b}),

L₂, b2, R₂, and c2 may each be the same as described herein,

R₂₁ to R₂₃, R₂₉ₐ, and R_{29b} may each be the same as described in connection with R₂,

two or more of R₂₁ to R₂₃ may optionally be linked to each other to form a C₅-C₃₀ carbocyclic group unsubstituted or substituted with at least one R₁₀ₐ, or a C₁-C₃₀ heterocyclic group unsubstituted or substituted with at least one R₁₀ₐ,

X₃₁ may be N or C(R₃₁), X₃₂ may be N or C(R₃₂), and X₃₃ may be N or C(R₃₃),

R₃₁ to R₃₃ may each be the same as described in connection with R₃,

two or more of R₃₁ to R₃₃ may optionally be linked to each other to form a C₅-C₃₀ carbocyclic group unsubstituted or substituted with at least one R₁₀ₐ, or a C₁-C₃₀ heterocyclic group unsubstituted or substituted with at least one R₁₀ₐ,

X₄₁ may be N or C(R₄₁), X₄₂ may be N or C(R₄₂), X₄₃ may be N or C(R₄₃), and X₄₄ may be N or C(R₄₄),

R₄₁ to R₄₄ may each be the same as described in connection with R₄, and

two or more of R₄₁ to R₄₄ may optionally be linked to each other to form a C₅-C₃₀ carbocyclic group unsubstituted or substituted with at least one R₁₀ₐ, or a C₁-C₃₀ heterocyclic group unsubstituted or substituted with at least one R₁₀ₐ.

In one or more embodiments,

Y₁ in Formula 2-1 may be N, and

a group represented by

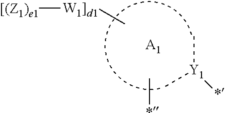

in Formula 2-1 may be a group represented by one of Formulae A1-1 to A1-3:

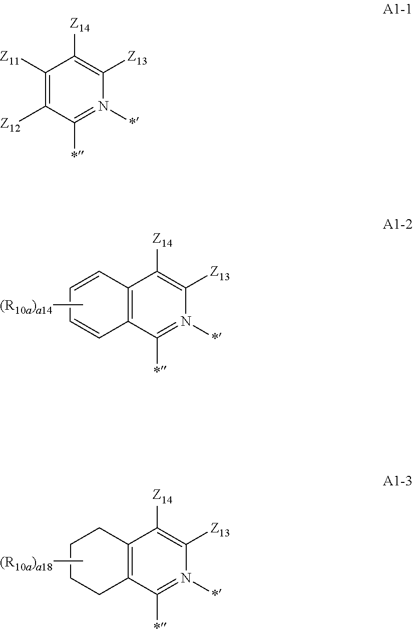

wherein, in Formulae A1-1 to A1-3,

Z₁ to Z₁₄ may each be the same as described in connection with Z₁,

R₁₀ₐ may be understood by referring to the description of R₁₀ₐ provided herein, and

a14 may be an integer from 0 to 4,

a18 may be an integer from 0 to 8,

*′ indicates a binding site to M₂ in Formula 2, and

*″ indicates a binding site to ring A₂.

For example, in Formulae A1-1 to A1-3, Z₁₄ may be a deuterated C₁-C₂₀ alkyl group, —Si(Q₃)(Q₄)(Q₅), or —Ge(Q₃)(Q₄)(Q₅).

In one or more embodiments,

Y₃ in Formula 2-2 may be N, and

a group represented by

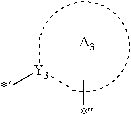

in Formula 2-2 may be a group represented by one of Formulae NR1 to NR48:

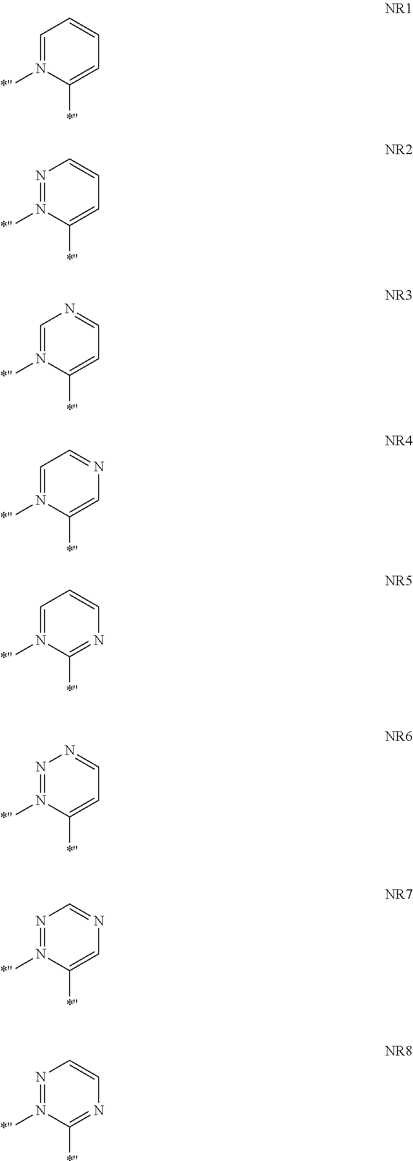

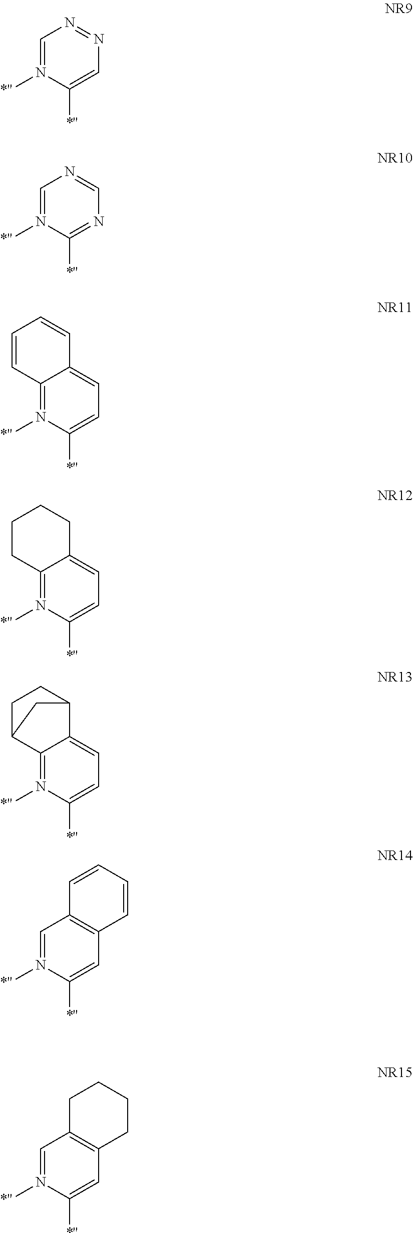

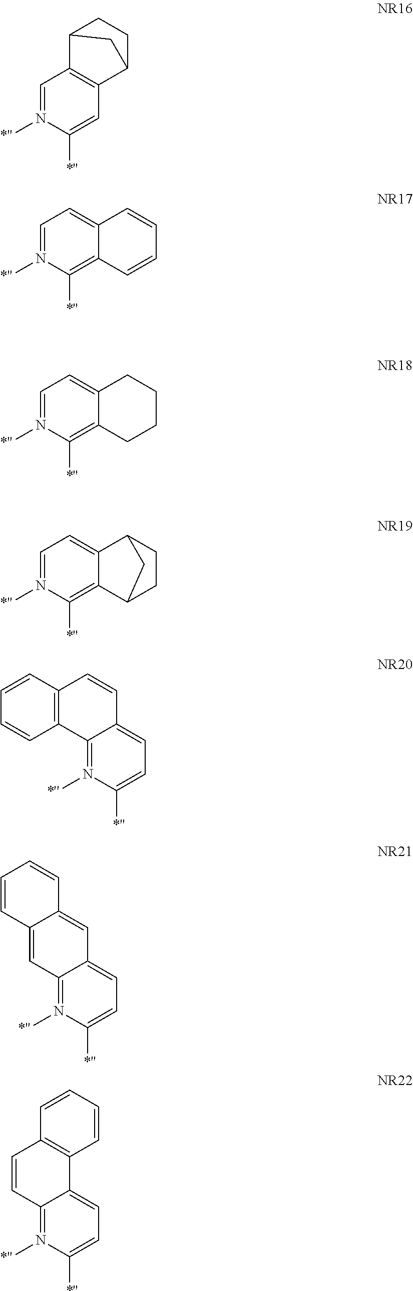

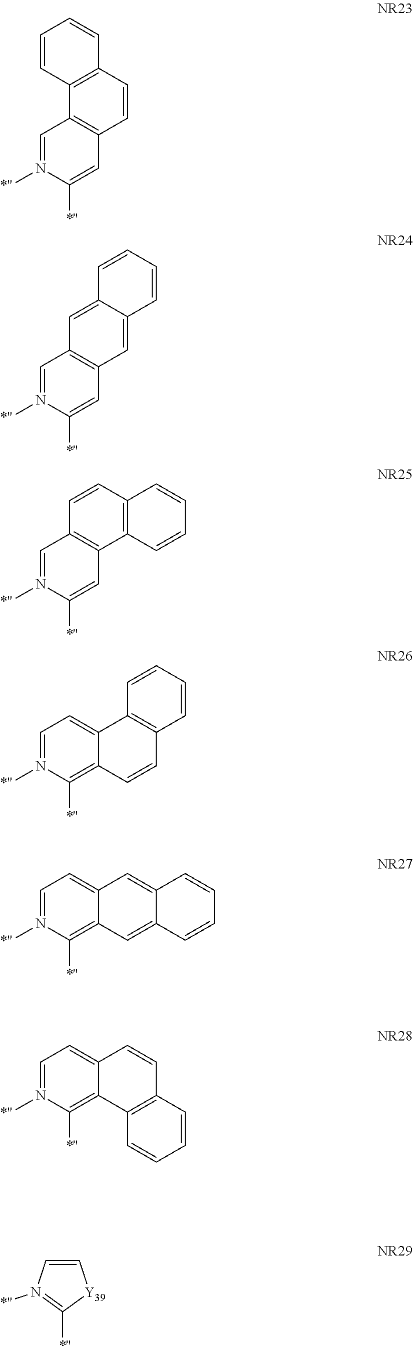

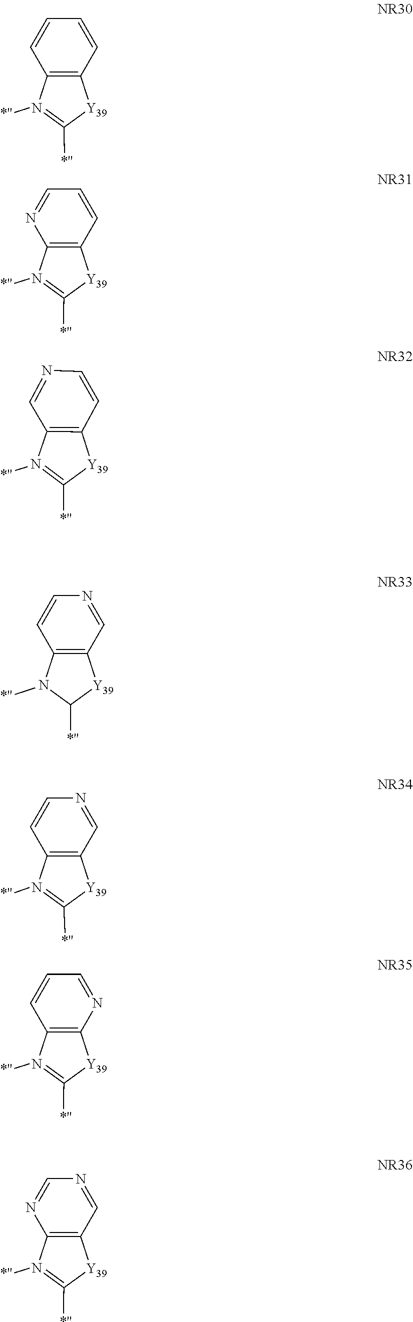

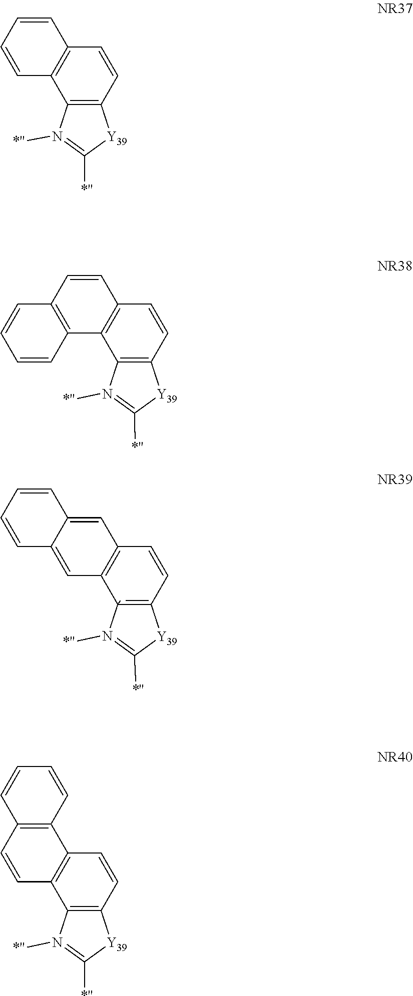

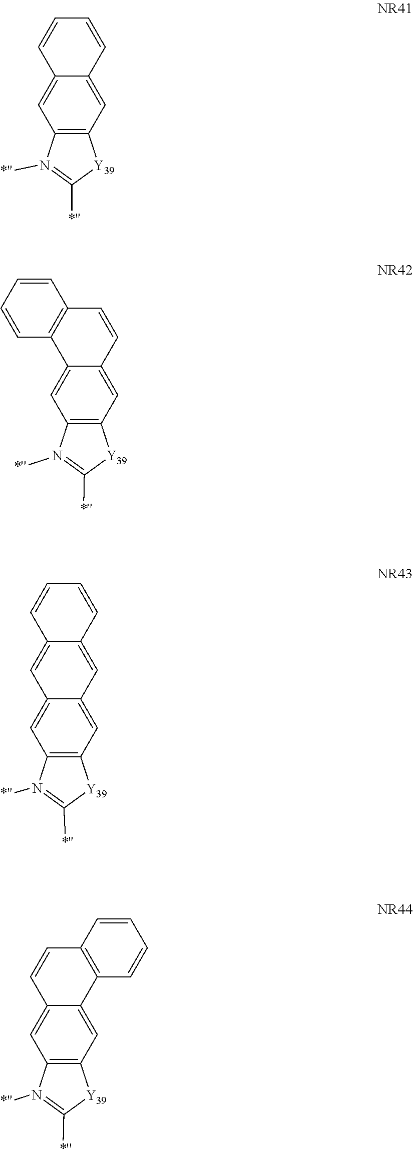

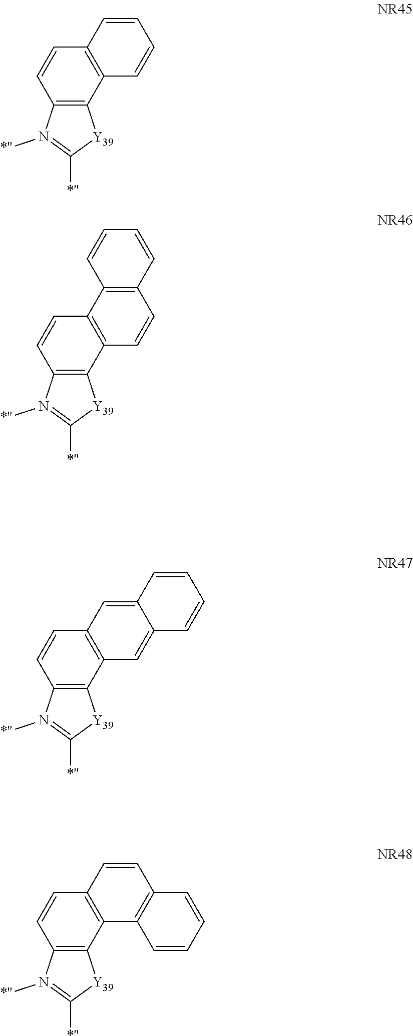

wherein, in Formulae NR1 to NR48,

Y₃₉ may be O, S, Se, N—[W₃—(Z₃)ₑ₃], C(Z₃₉ₐ)(Z_{39b}), or Si(Z₃₉ₐ)(Z_{39b}),

W₃, Z₃, and e3 may each be the same as described herein, and Z₃₉a and Z_{39b} may each be the same as described in connection with Z₃,

*′ indicates a binding site to M₂ in Formula 2, and

*″ indicates a binding site to ring A₄.

In one or more embodiments,

in Formulae 2-1 and 2-2, each of Y₂ and Y₄ may be C, and

a group represented by

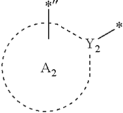

in Formula 2-1 and

a group represented by

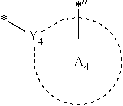

in Formula 2-2

may each independently be a group represented by one of Formulae CR1 to CR29:

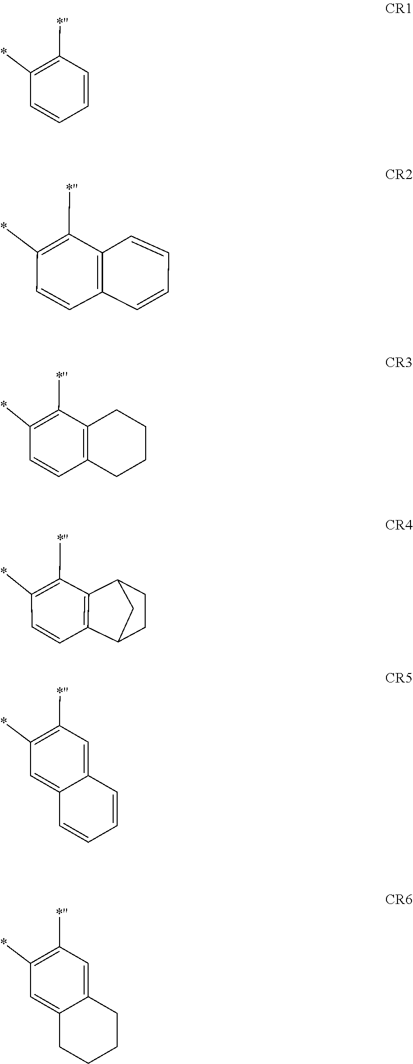

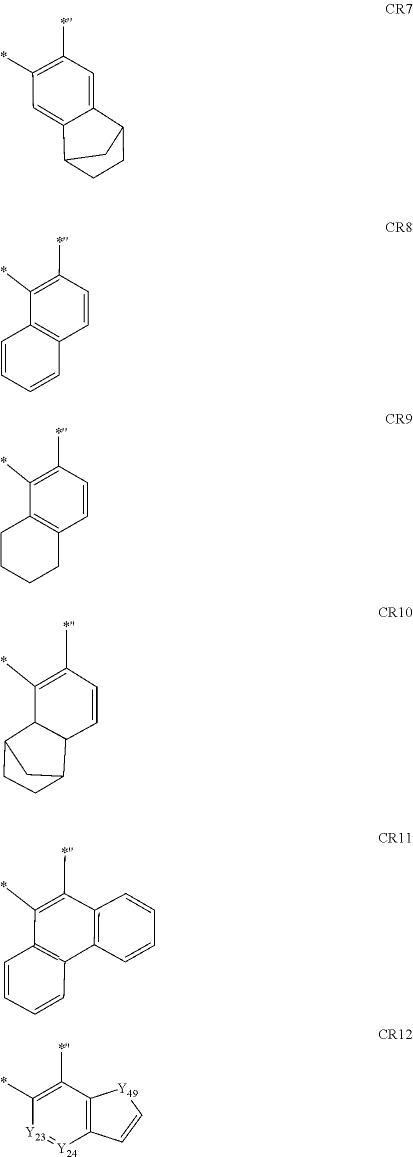

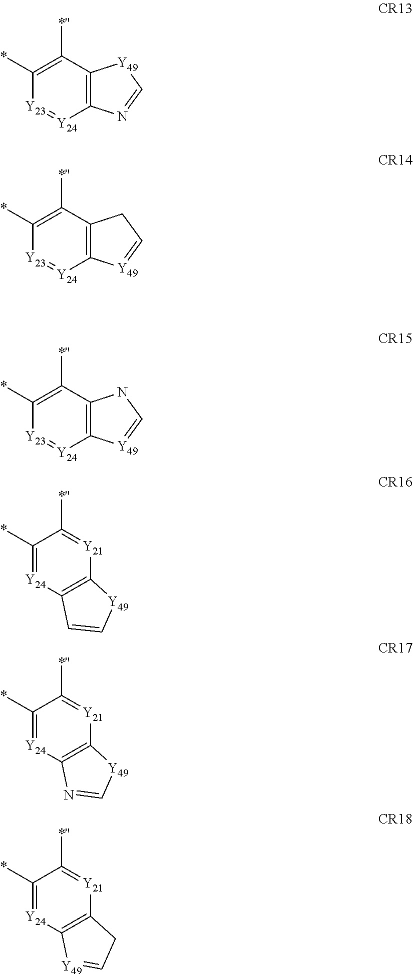

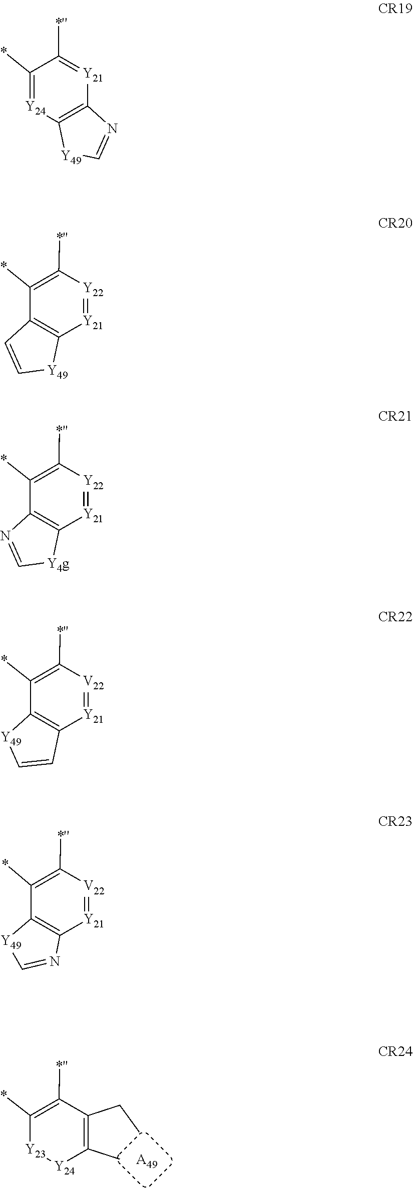

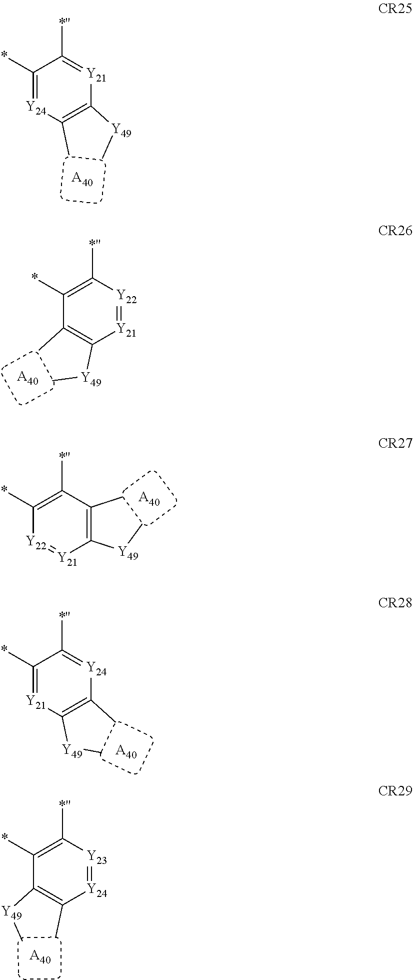

wherein, in Formulae CR1 to CR29,

Y₄₉ may be 0, S, Se, N—[W₂—(Z₂)ₑ₂], N—[W₄—(Z₄)ₑ₄], C(Z₂₉ₐ)(Z_{29b}), C(Z₄₉ₐ)(Z_{49b}), Si(Z₂₉ₐ)(Z_{29b}), or Si(Z₄₉ₐ)(Z_{49b}),

W₂, W₄, Z₂, Z₄, e2, and e4 may each be the same as described herein, Z₂₉a and Z_{29b} may each be the same as described in connection with Z₂, and Z₄₉a and Z_{49b} may each be the same as described in connection with Z₄,

Y₂₁ to Y₂₄ may each independently be N or C,

ring A₄₀ may be a C₅-C₃₀ carbocyclic group or a C₁-C₃₀ heterocyclic group (for example, a benzene group, a naphthalene group, a phenanthrene group, a pyridine group, a pyrimidine group, a pyrazine group, a pyridazine group, a quinoline group, an isoquinoline group, a benzoquinoline group, a benzoisoquinoline group, a quinoxaline group, a benzoquinoxaline group, a quinazoline group, or a benzoquinazoline group),

* indicates a binding site to M₂ in Formula 2, and

*″ indicates a binding site to ring A₁ in Formula 2-1 or ring A₃ in Formula 2-2.

In one or more embodiments,

a group represented by

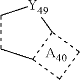

in Formulae CR24 to CR29 may be a group represented by one of Formulae CR(1) to CR(13):

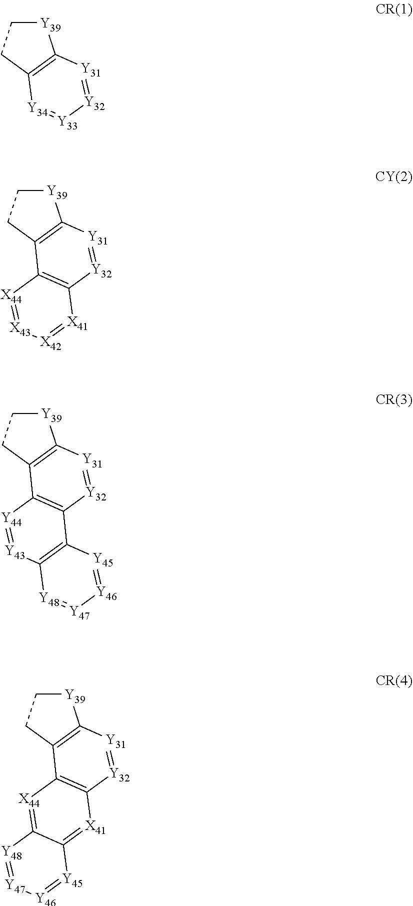

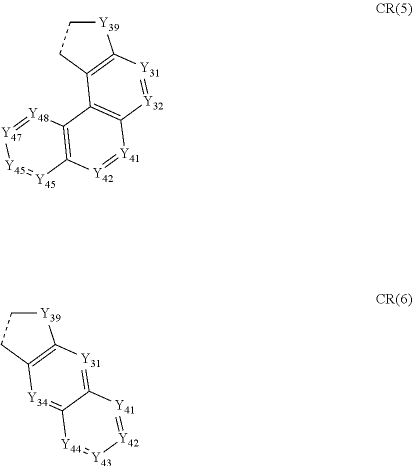

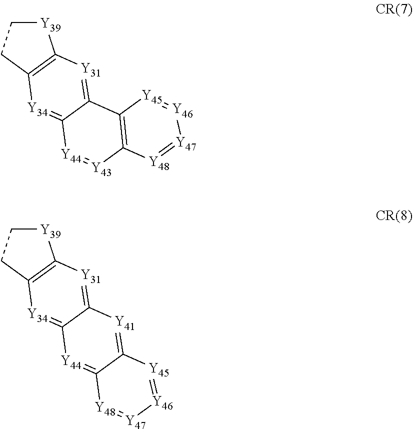

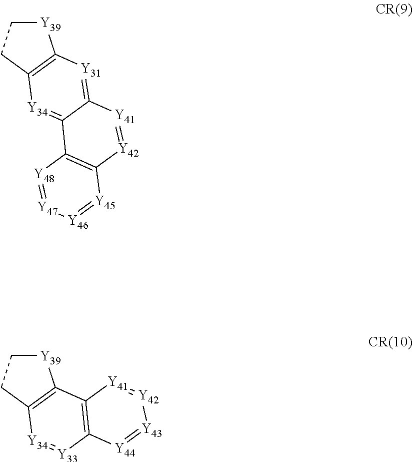

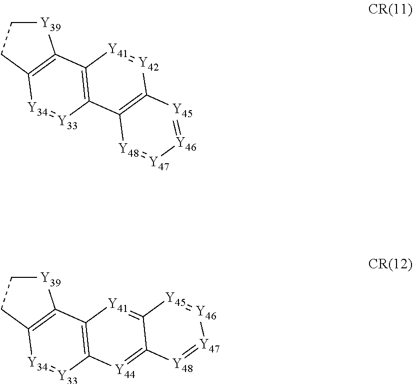

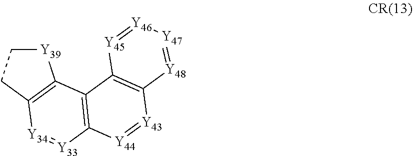

wherein, in Formulae CR(1) to CR(13),

Y₃₉ may be the same as described herein in connection with Y₄₉, and

Y₃₁ to Y₃₄ and Y₄₁ to Y₄₈ may each independently be C or N.

In one or more embodiments, the platinum-containing organometallic compound may include at least one deuterium.

In one or more embodiments, the iridium-containing organometallic compound may include at least one deuterium.

For example, the platinum-containing organometallic compound may be a compound of Group 1-1 to Group 1-4:

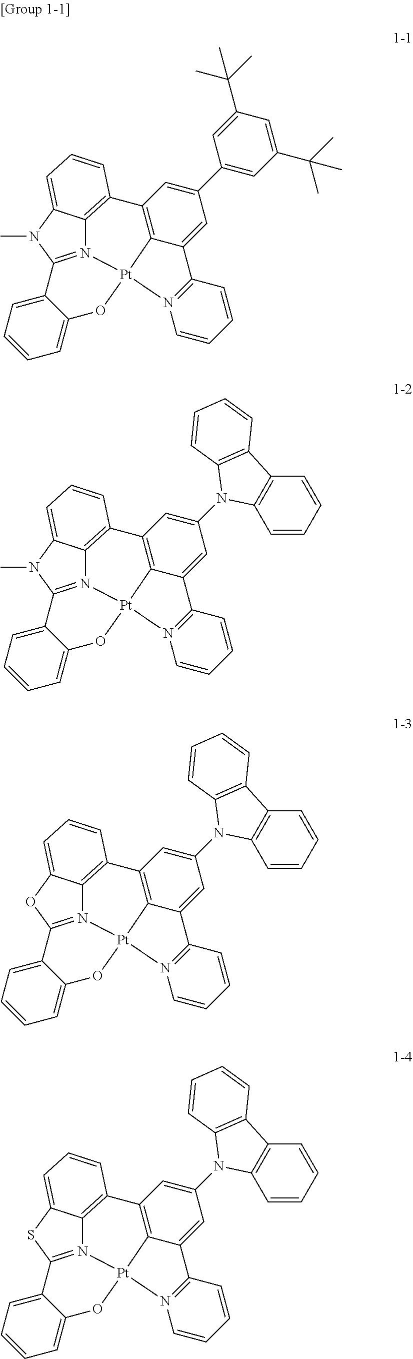

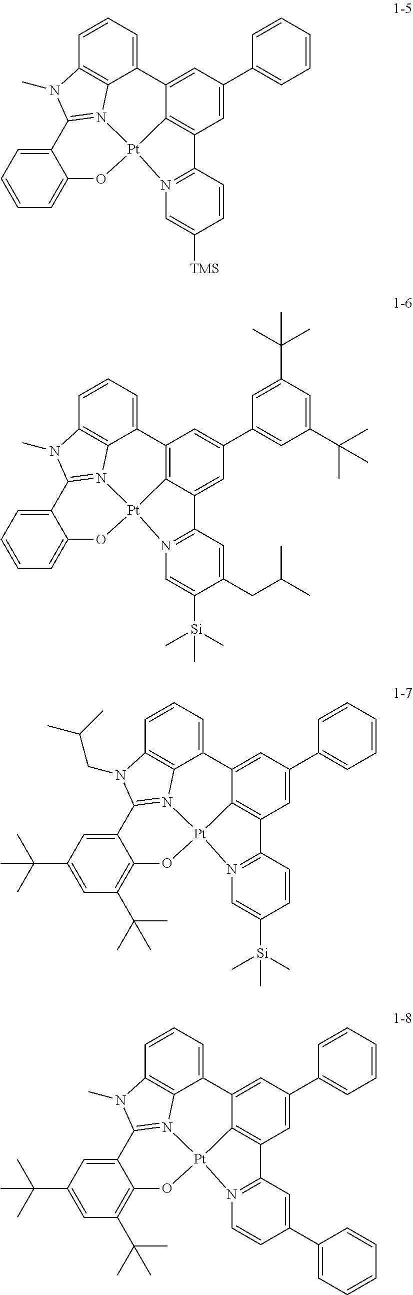

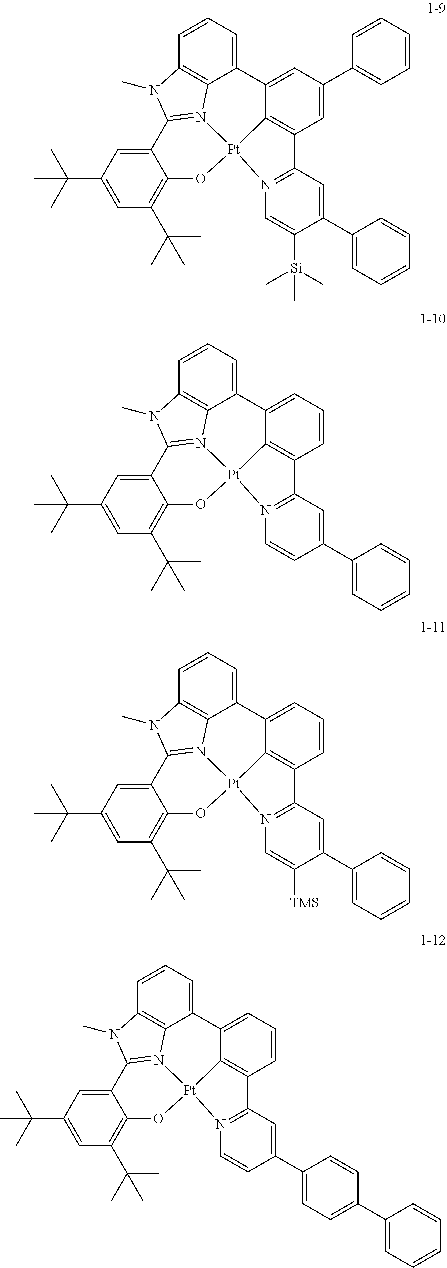

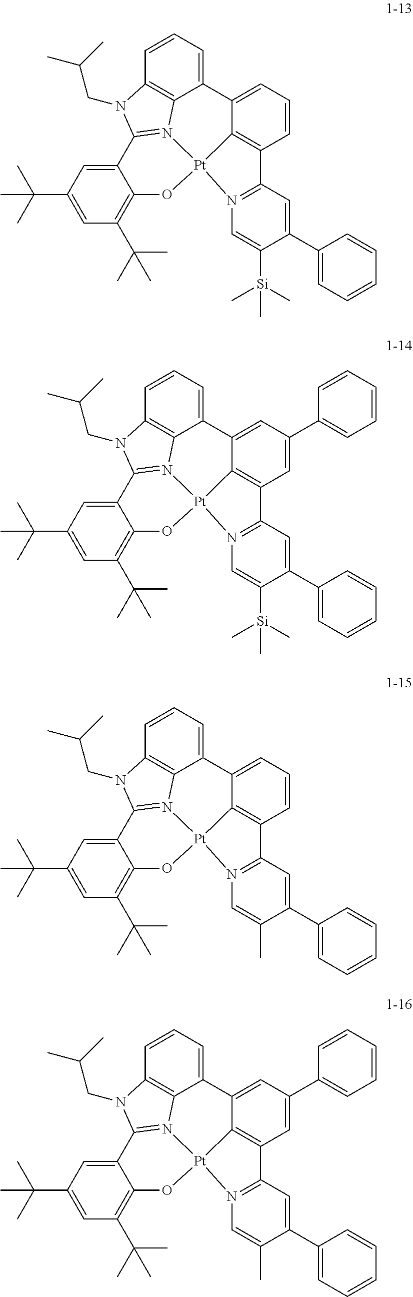

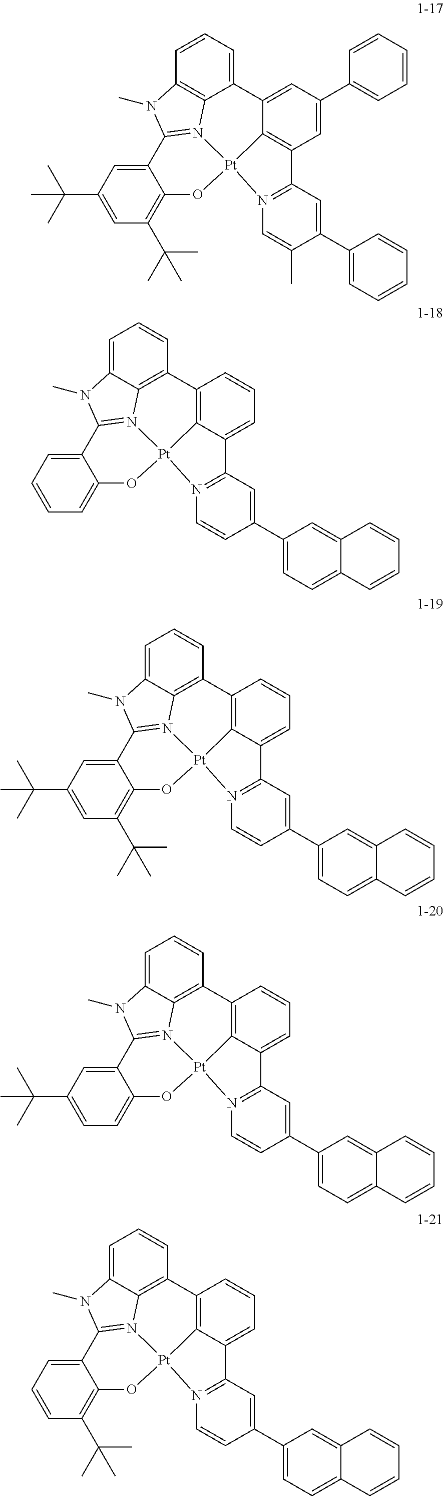

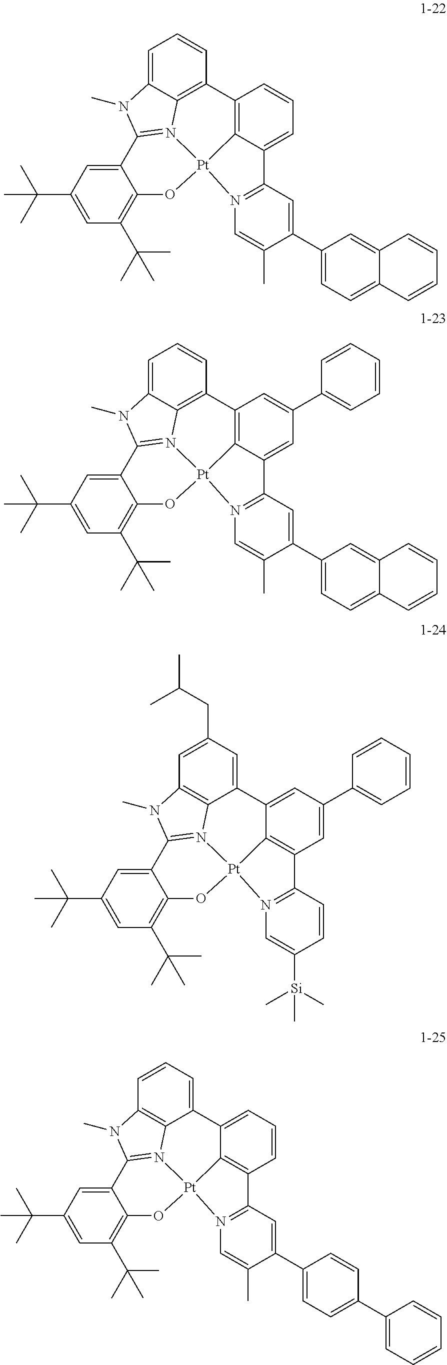

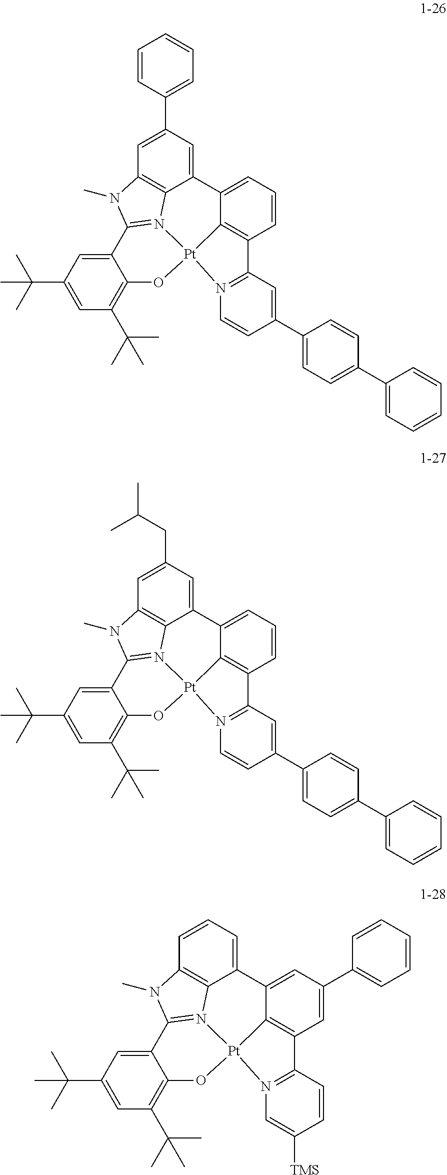

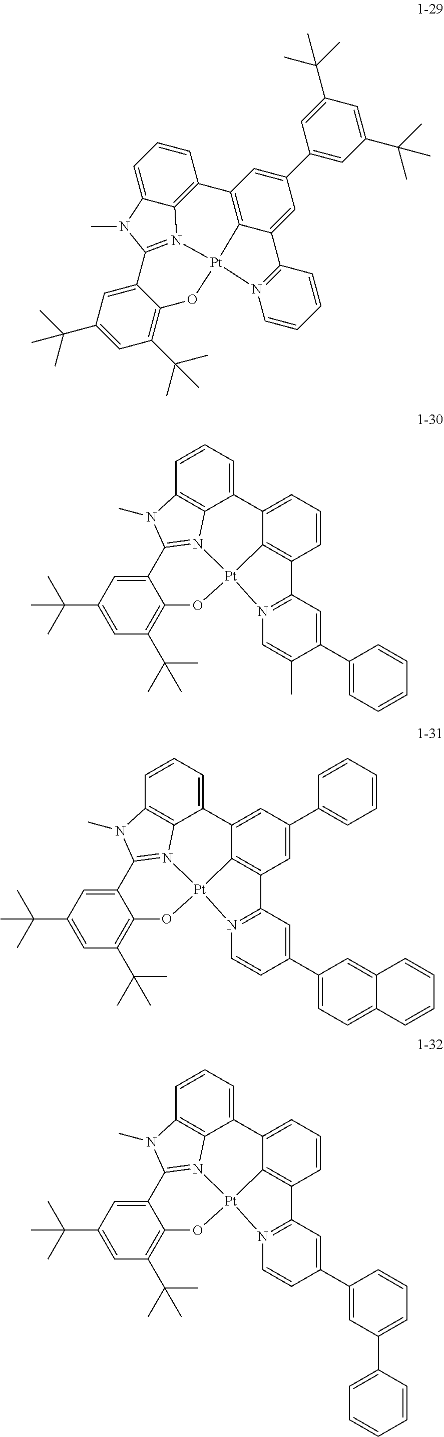

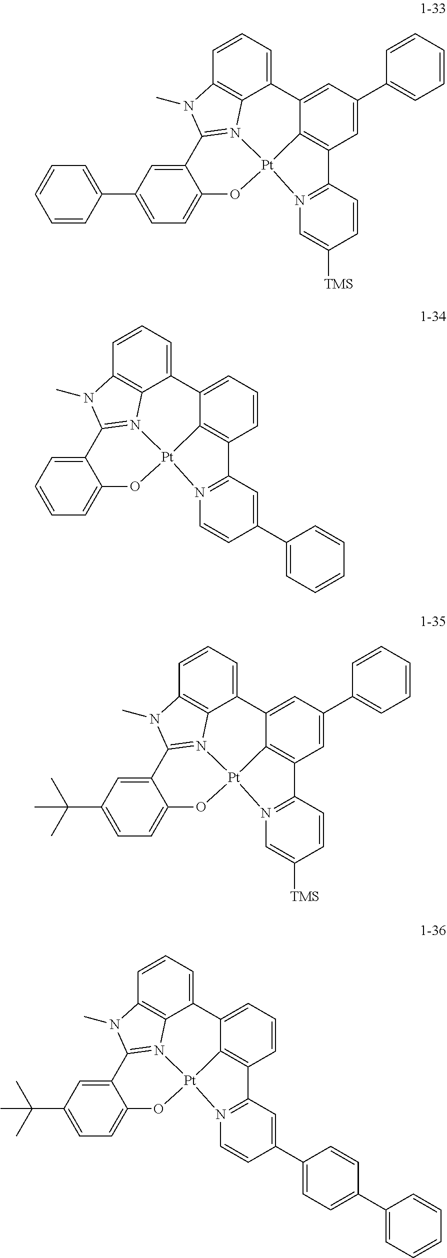

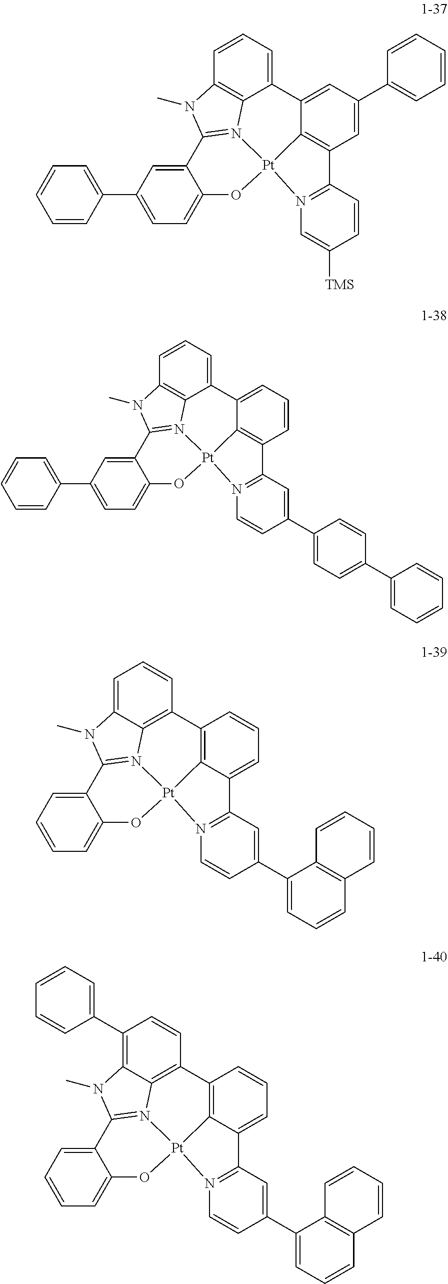

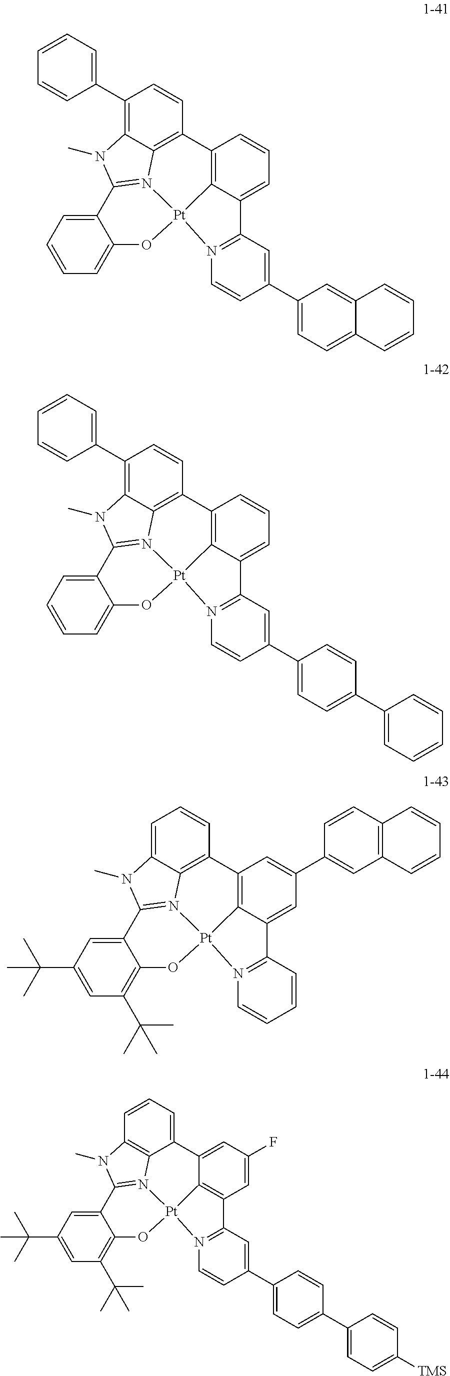

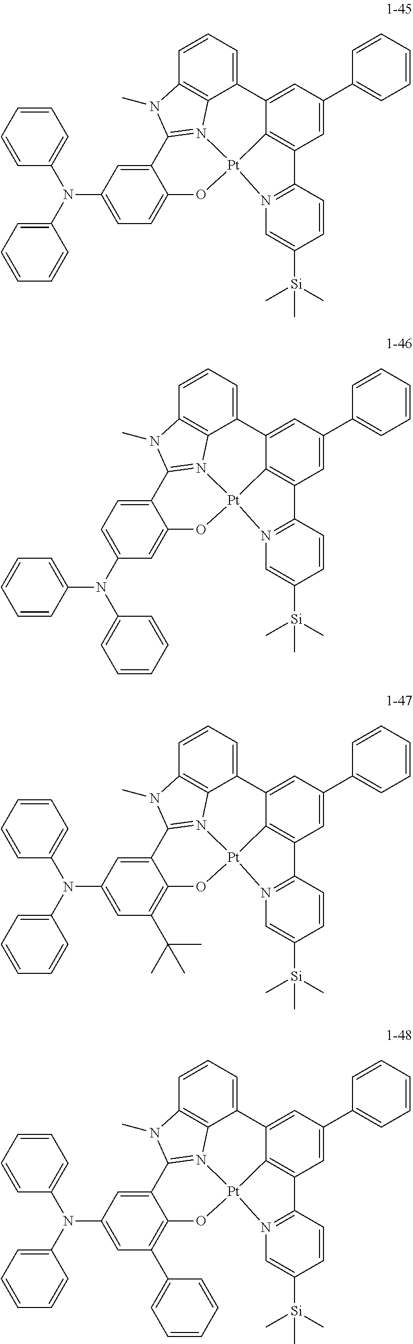

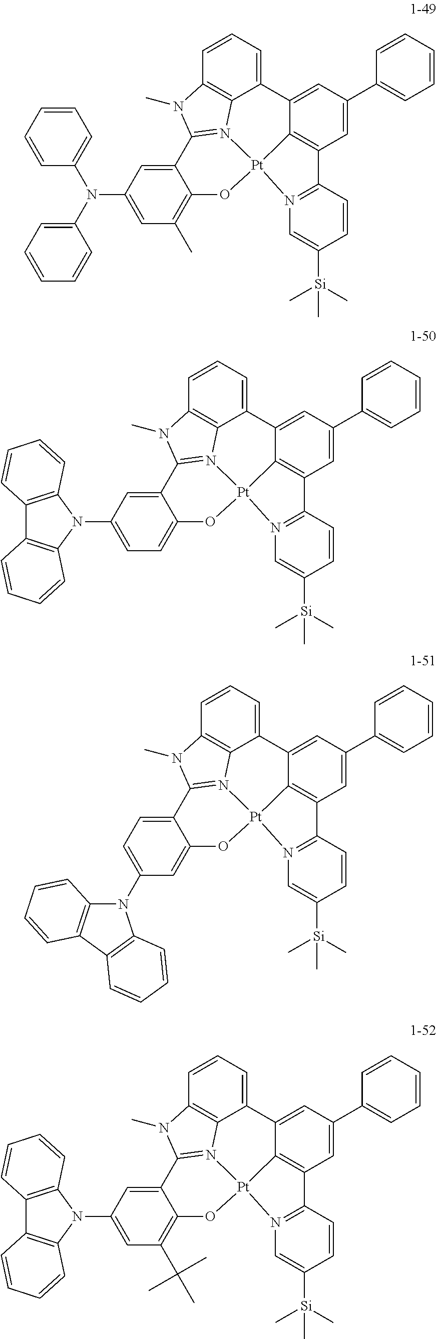

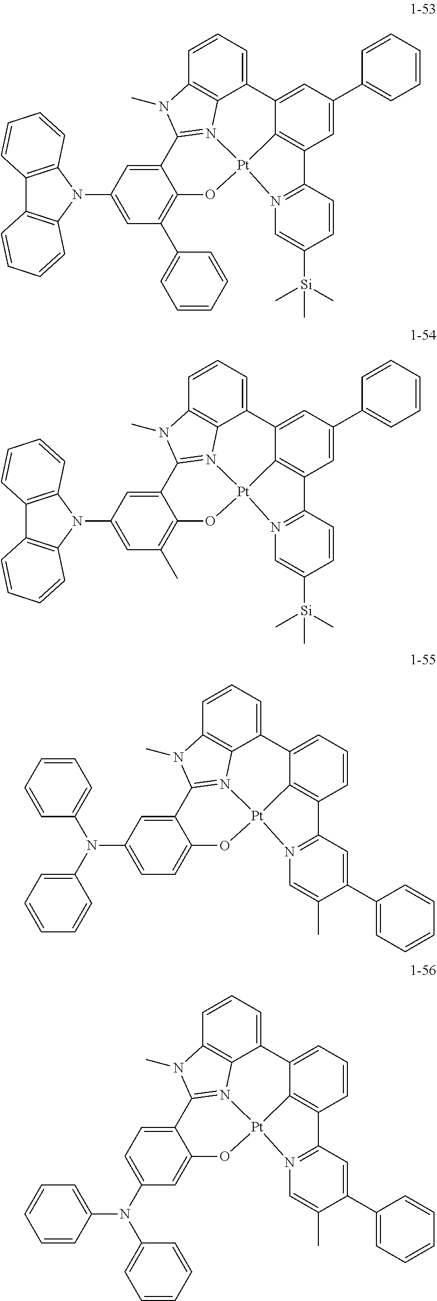

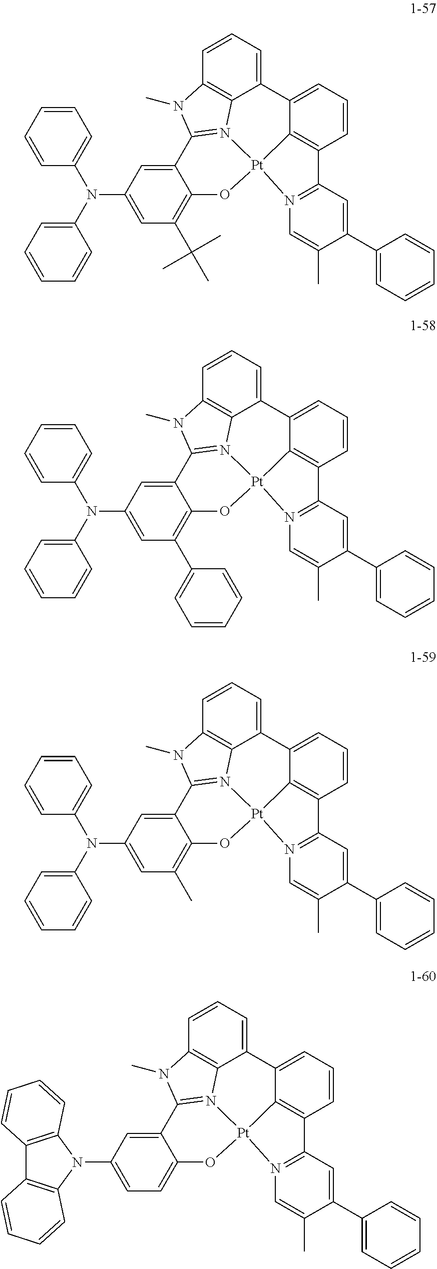

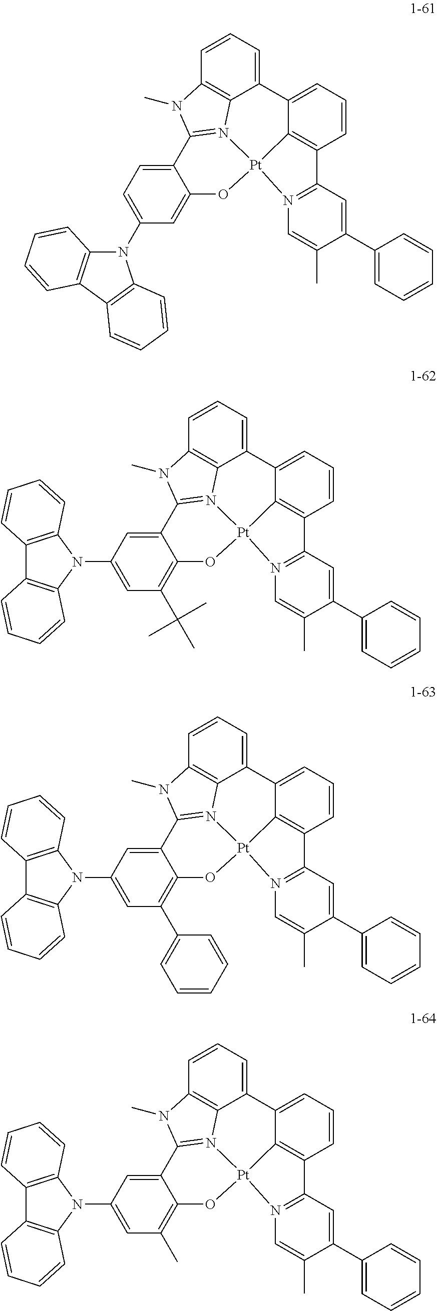

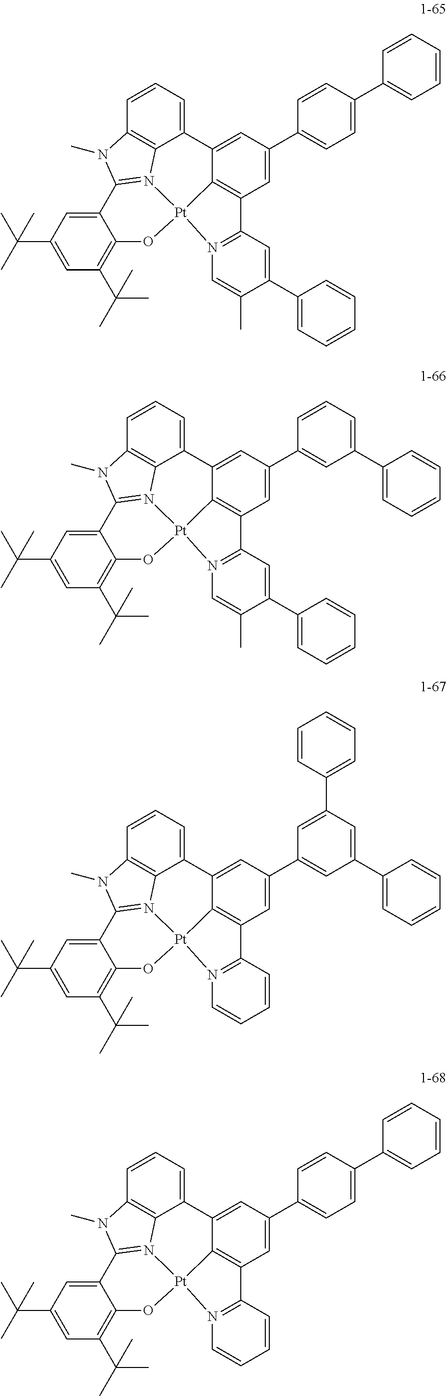

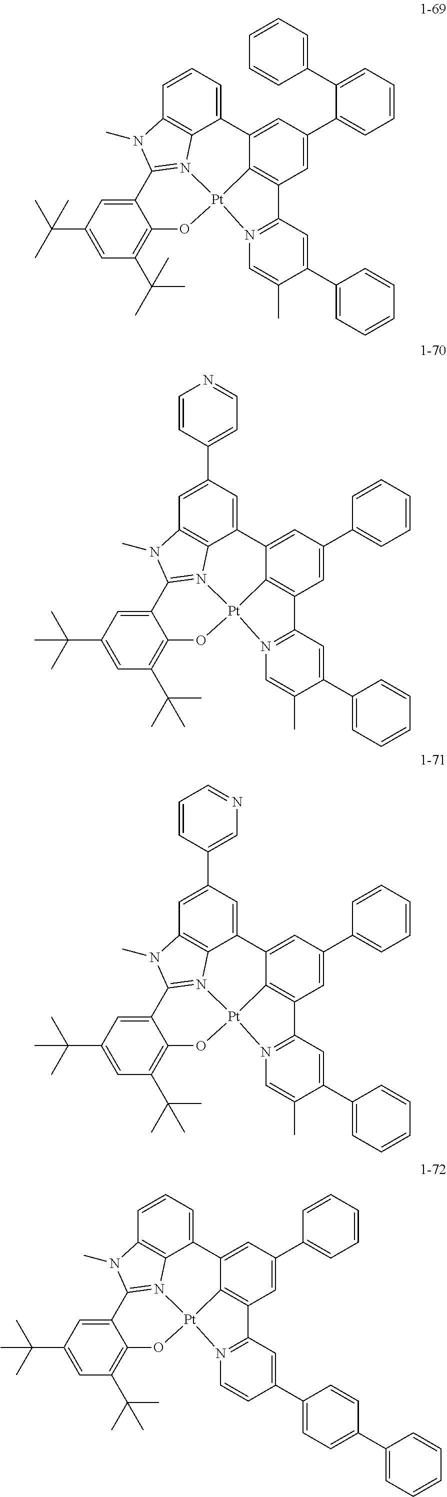

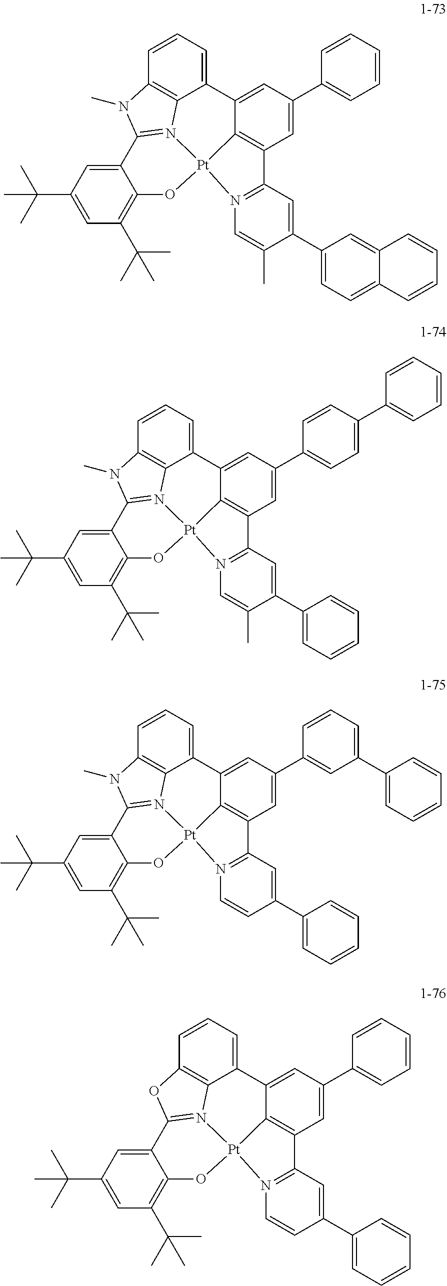

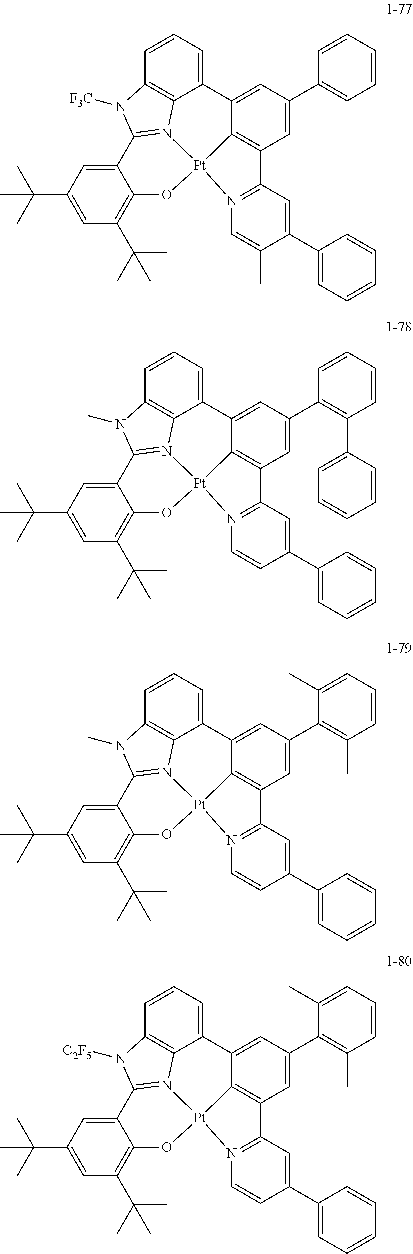

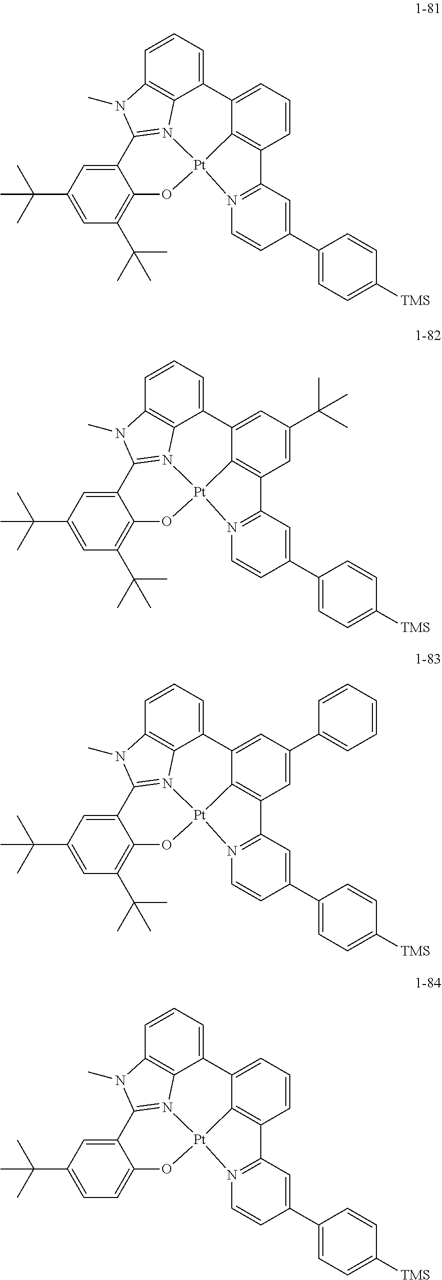

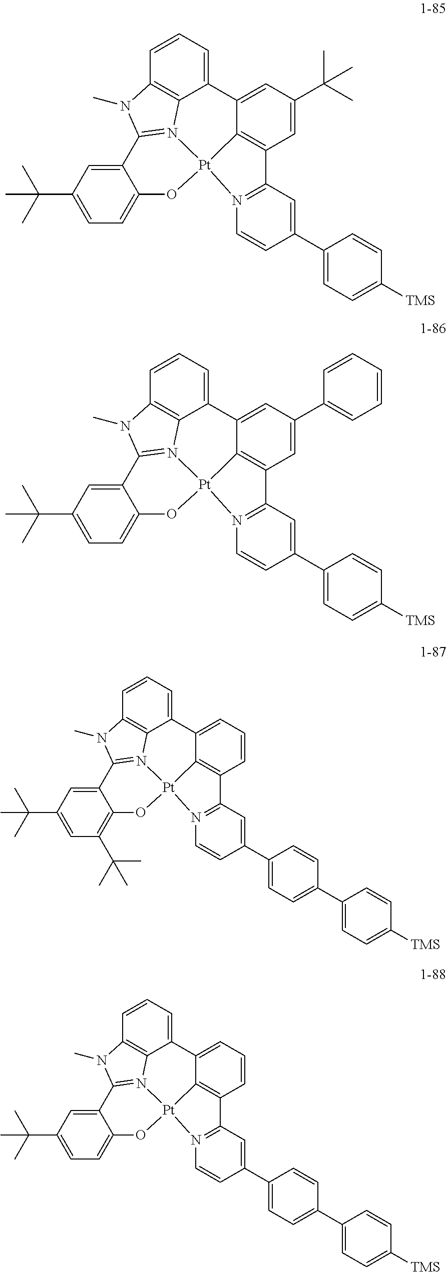

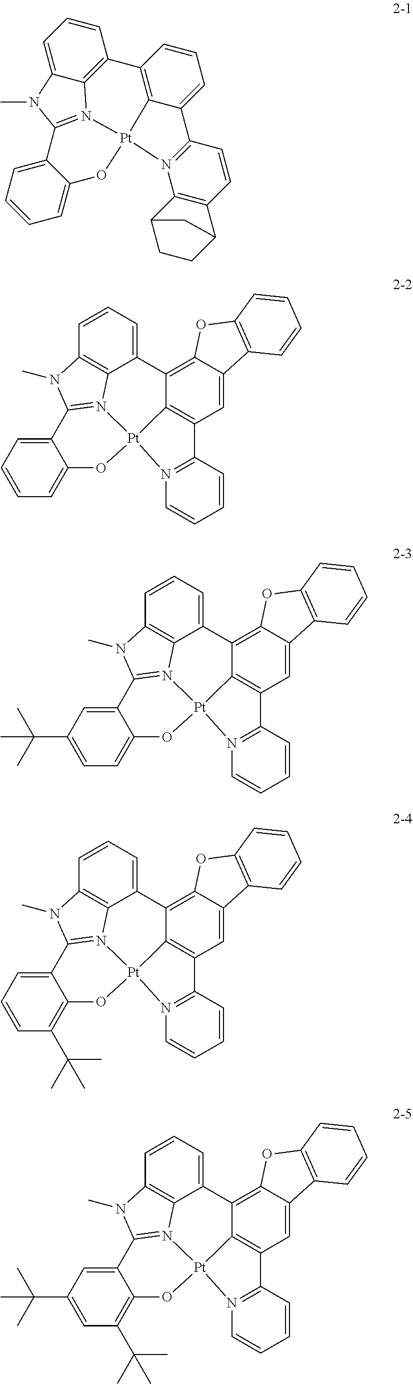

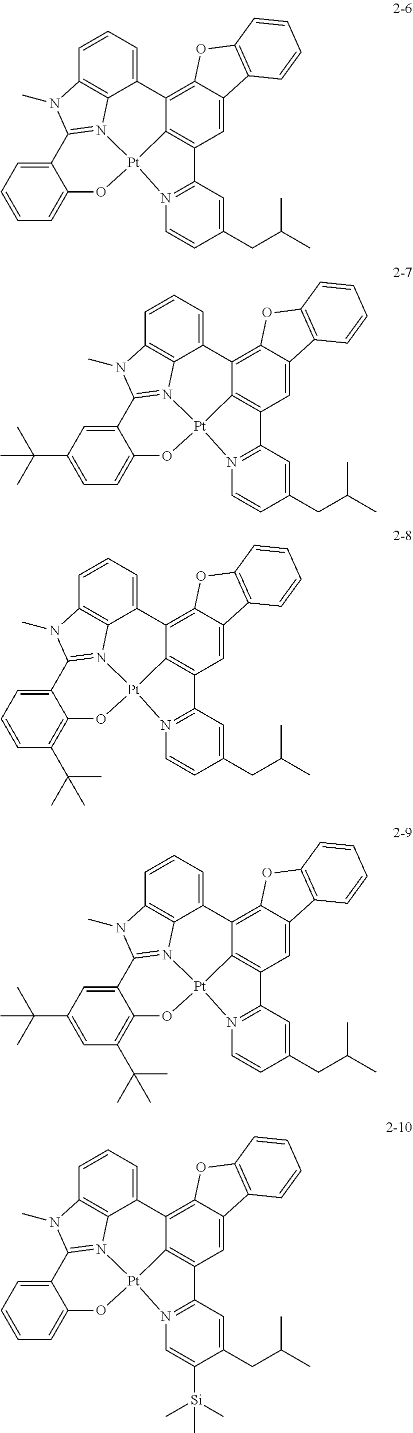

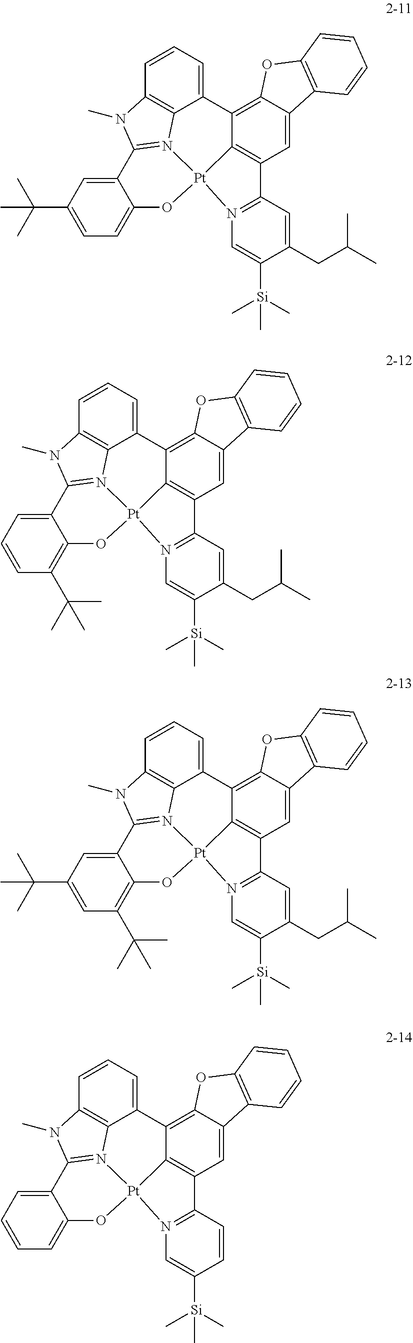

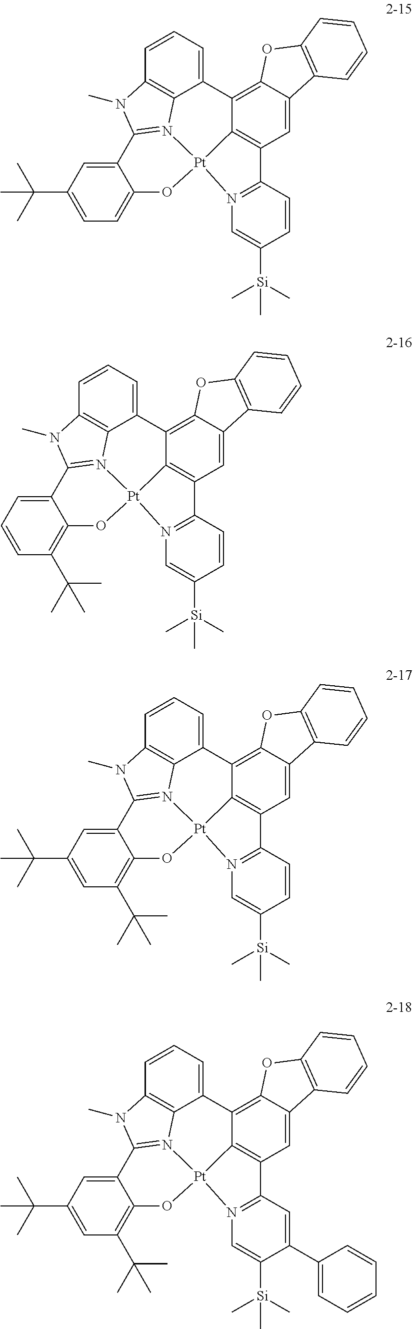

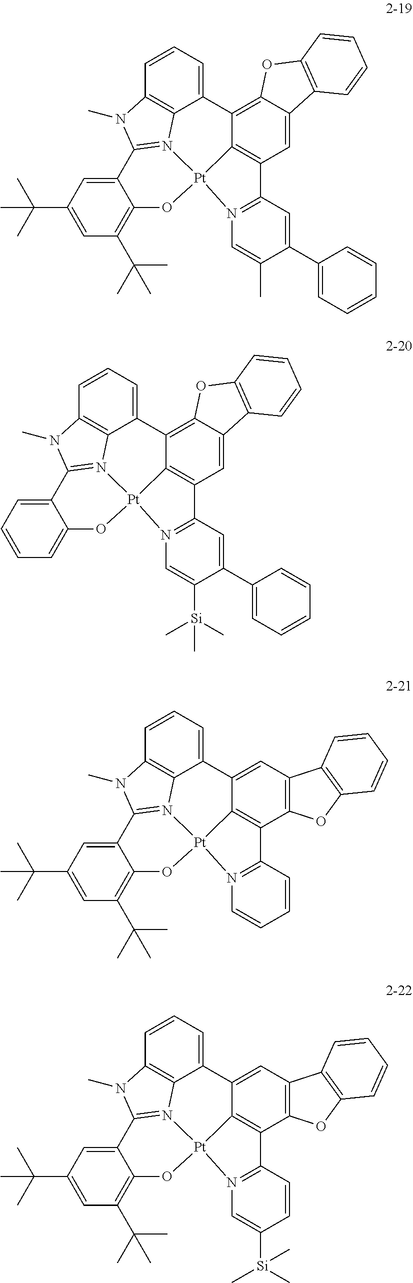

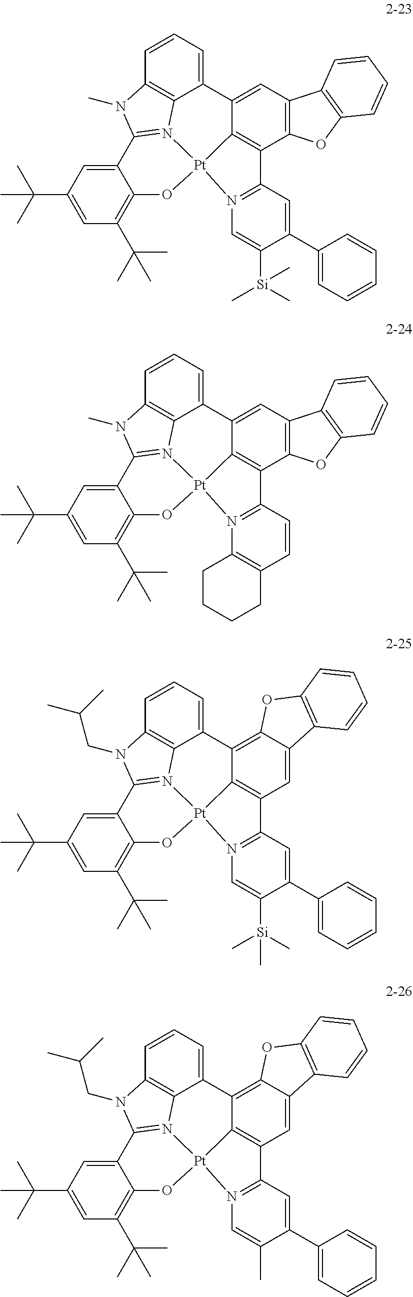

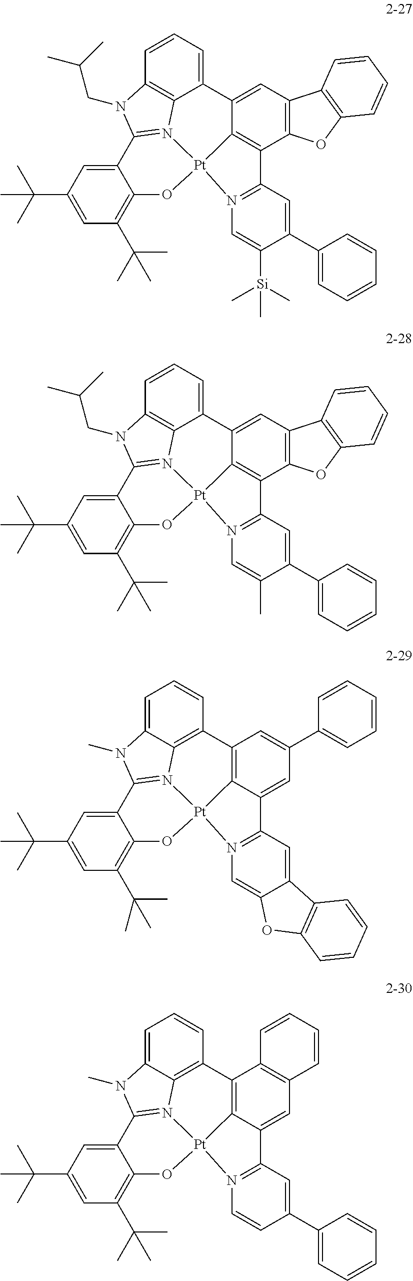

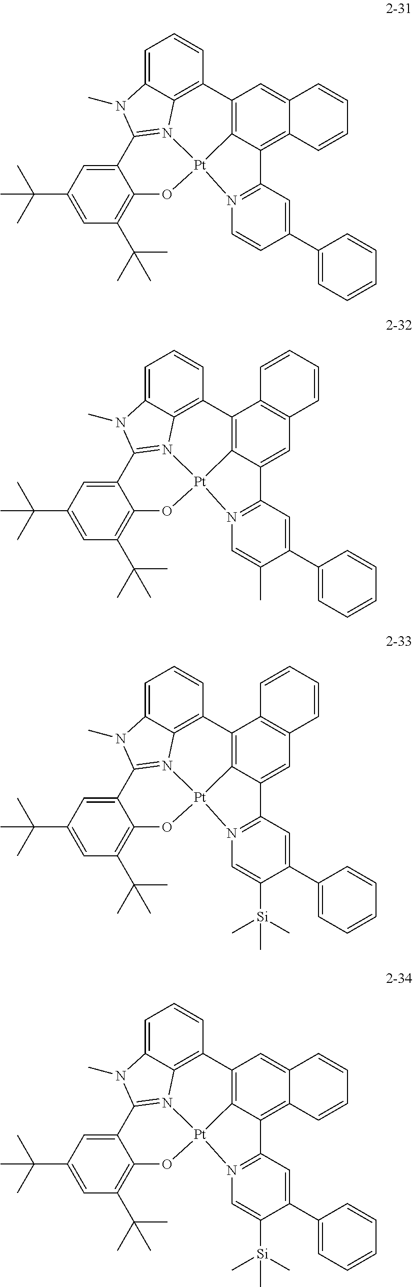

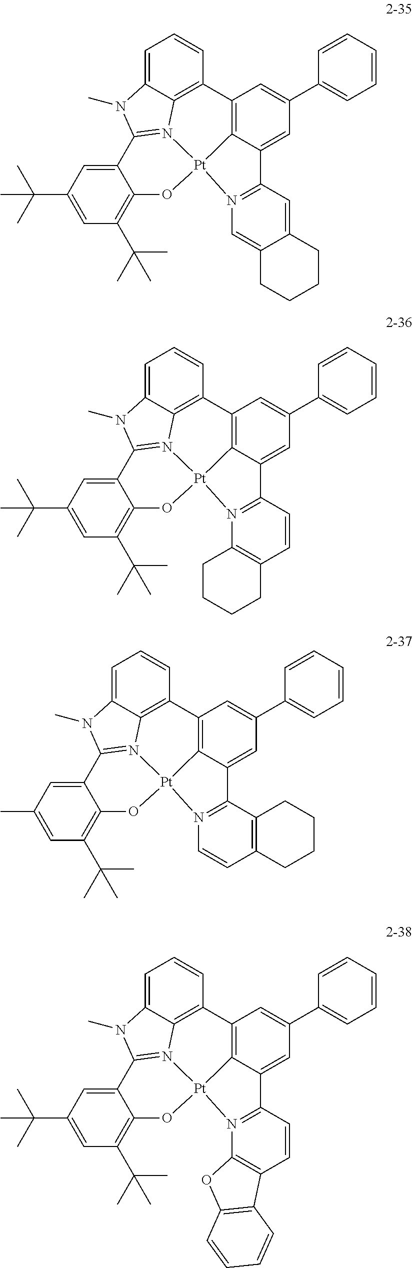

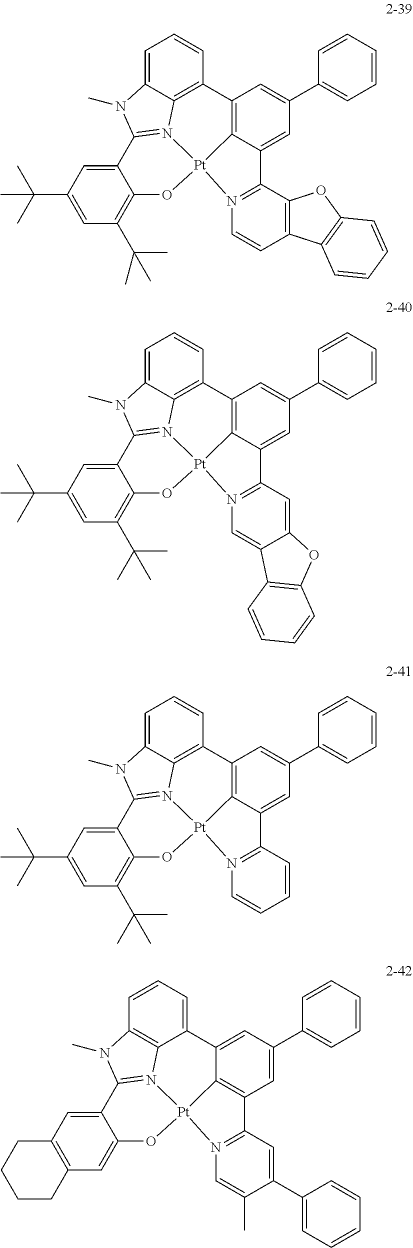

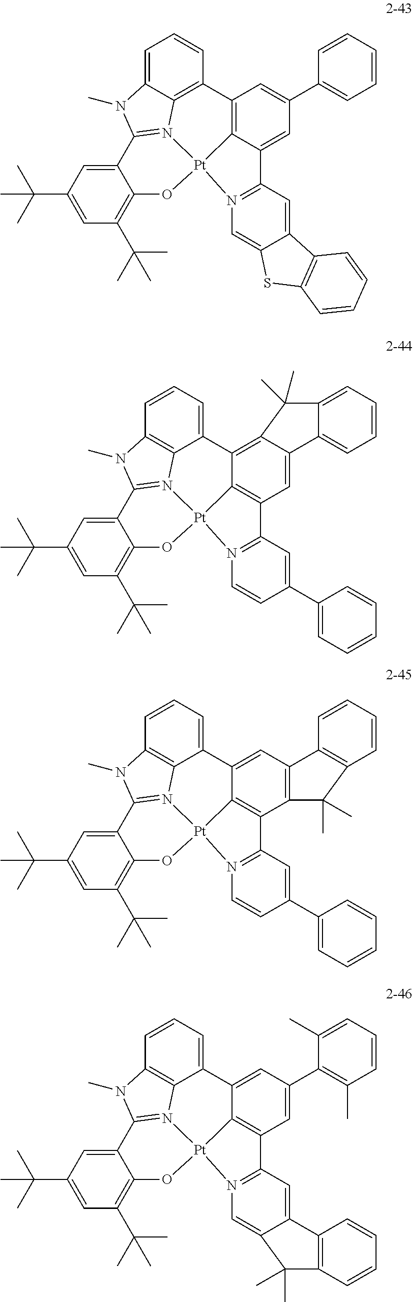

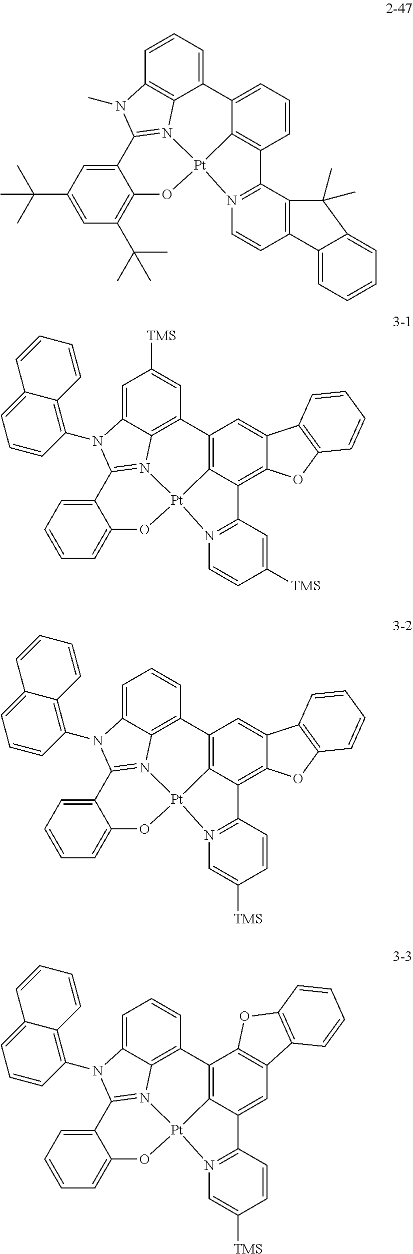

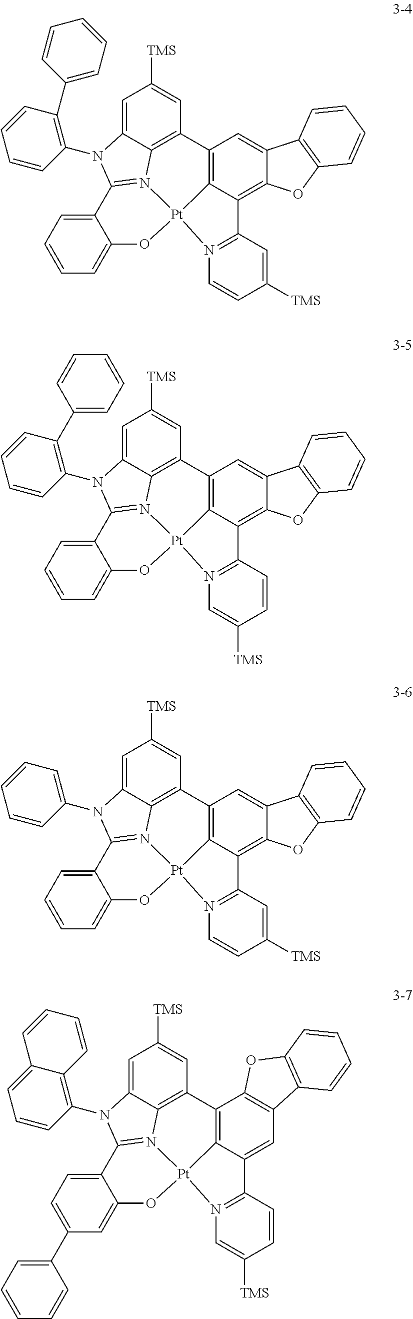

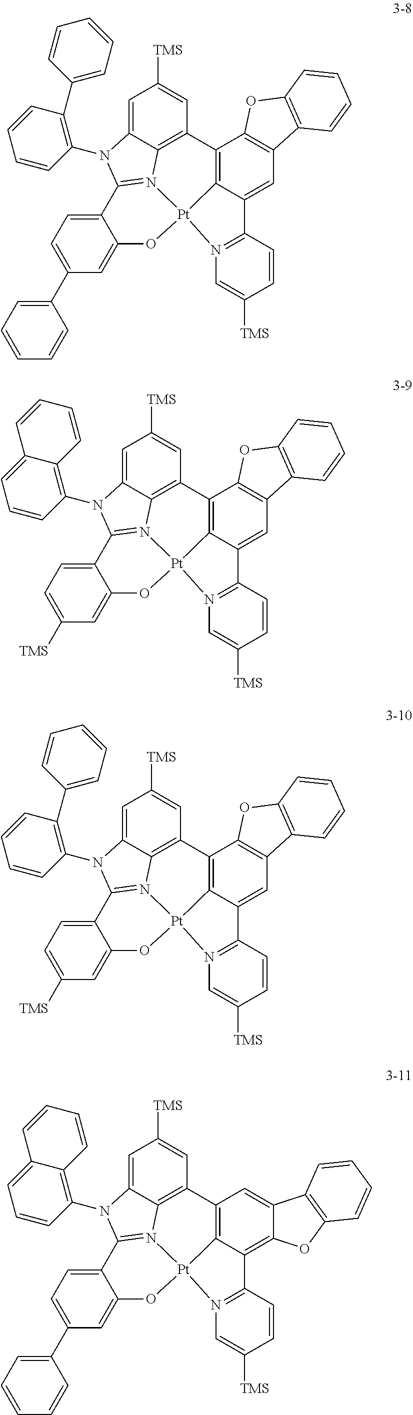

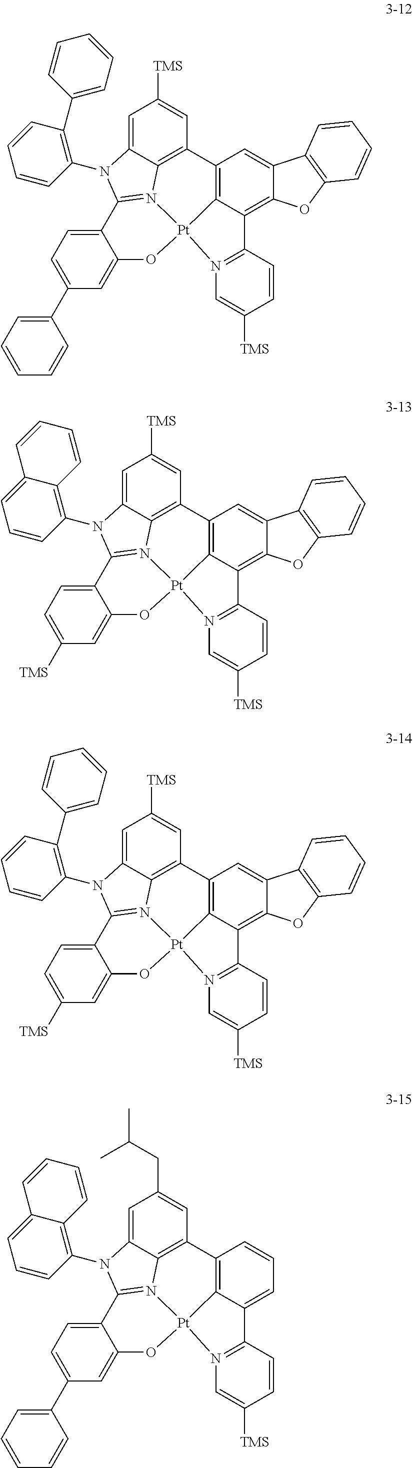

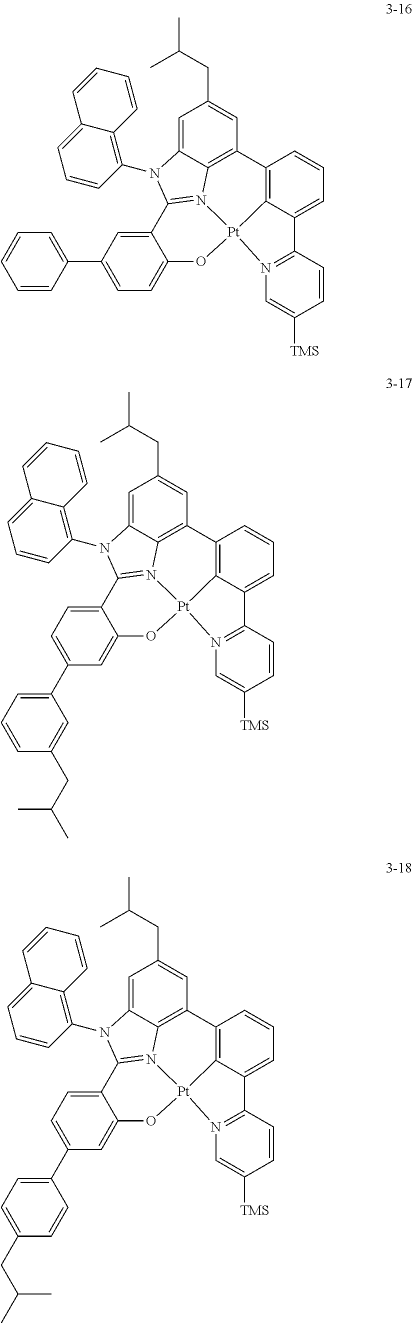

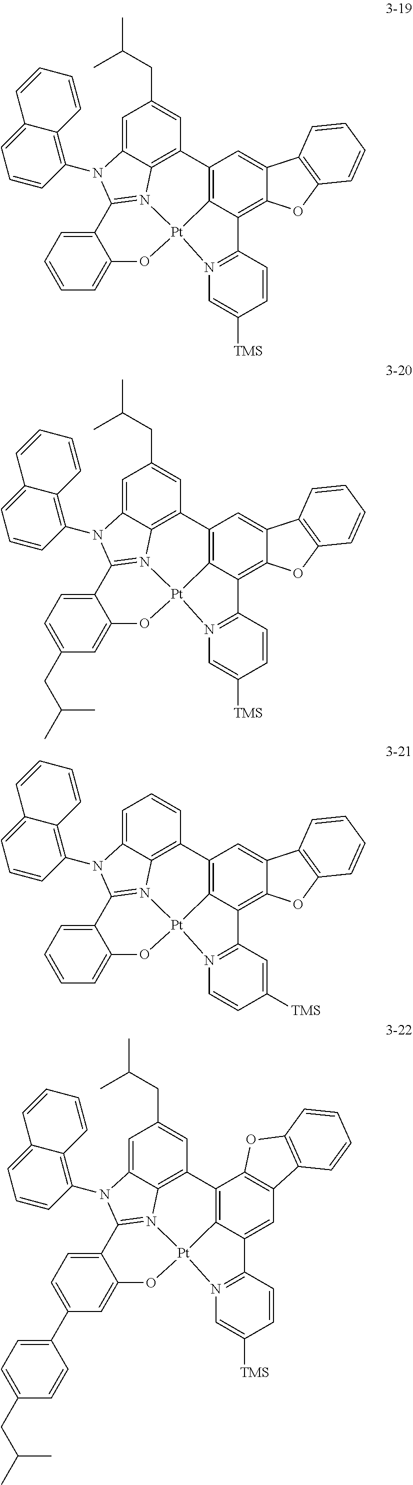

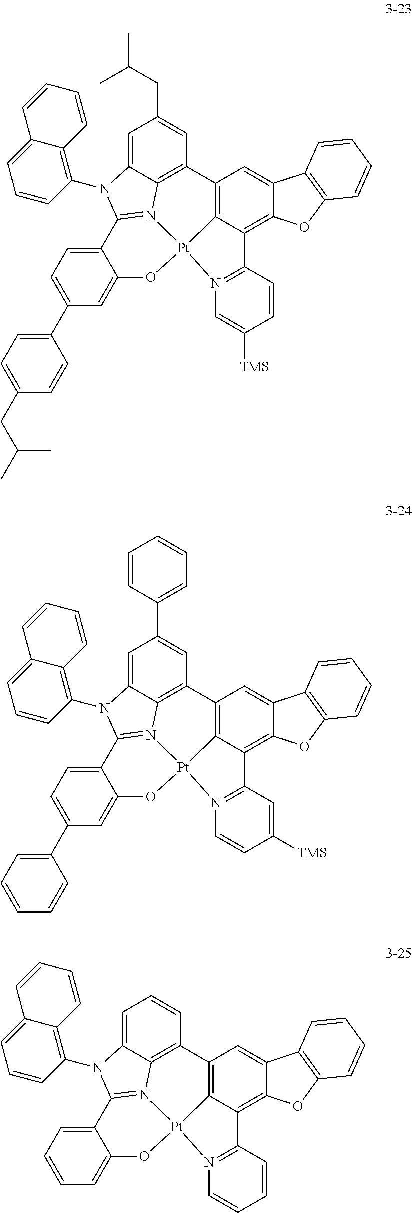

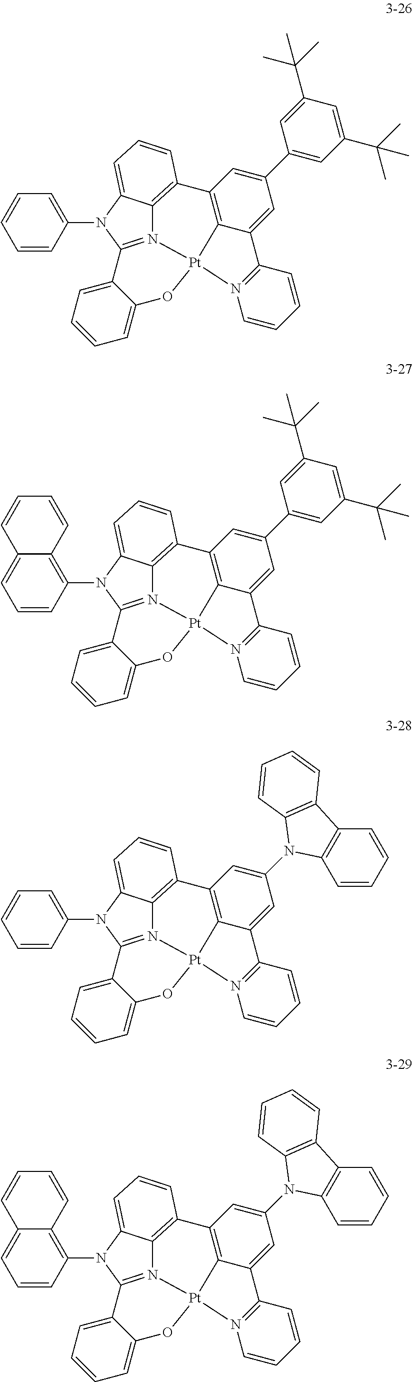

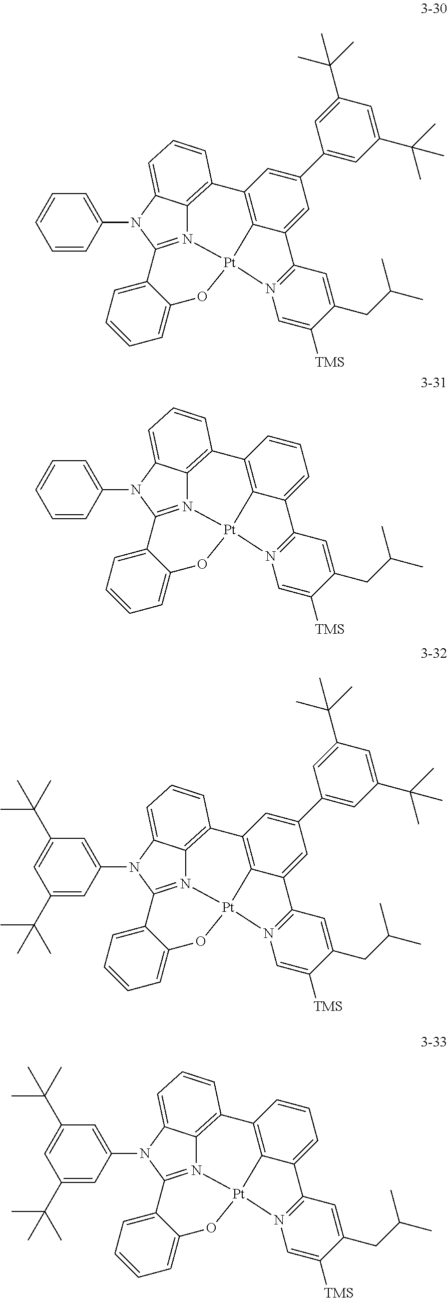

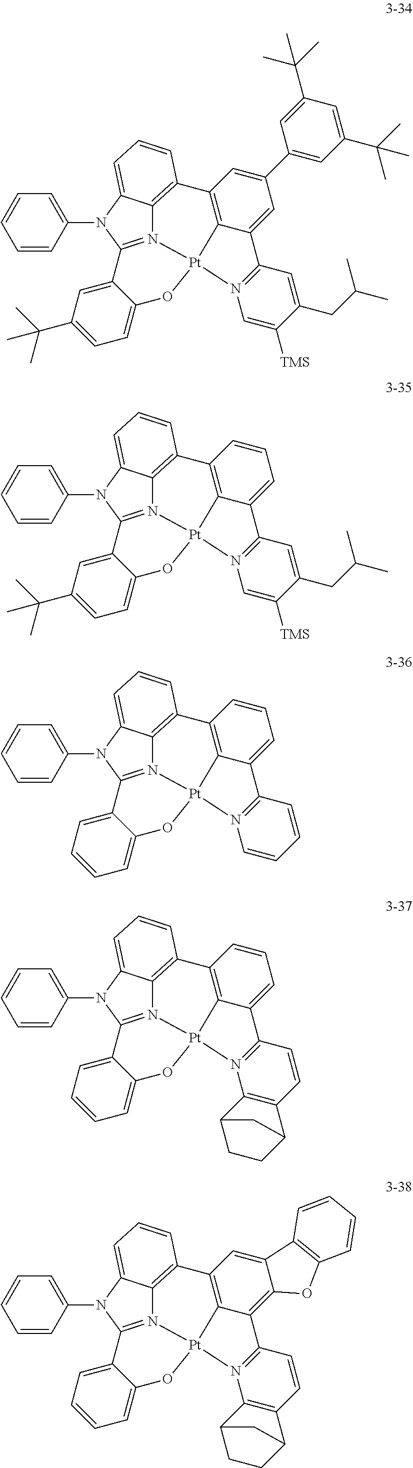

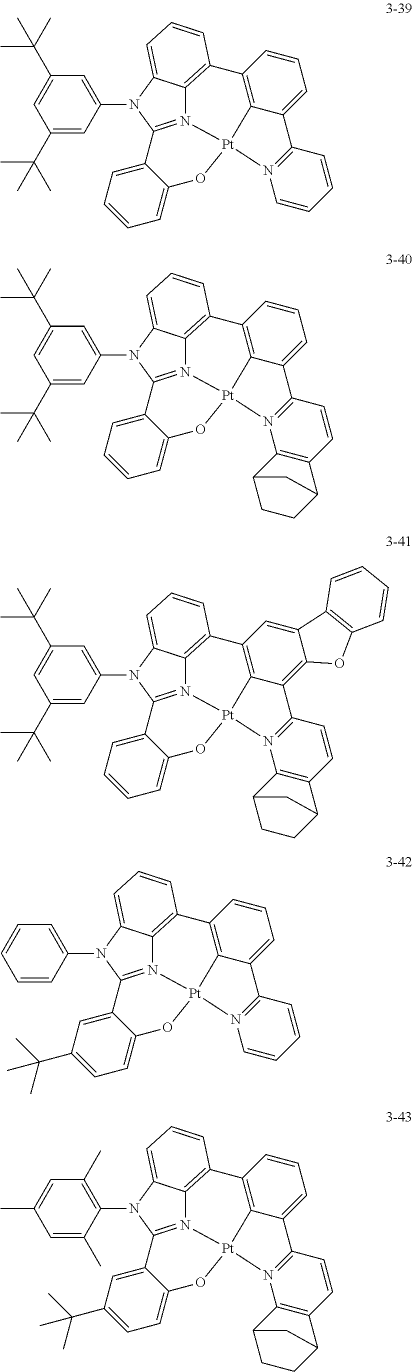

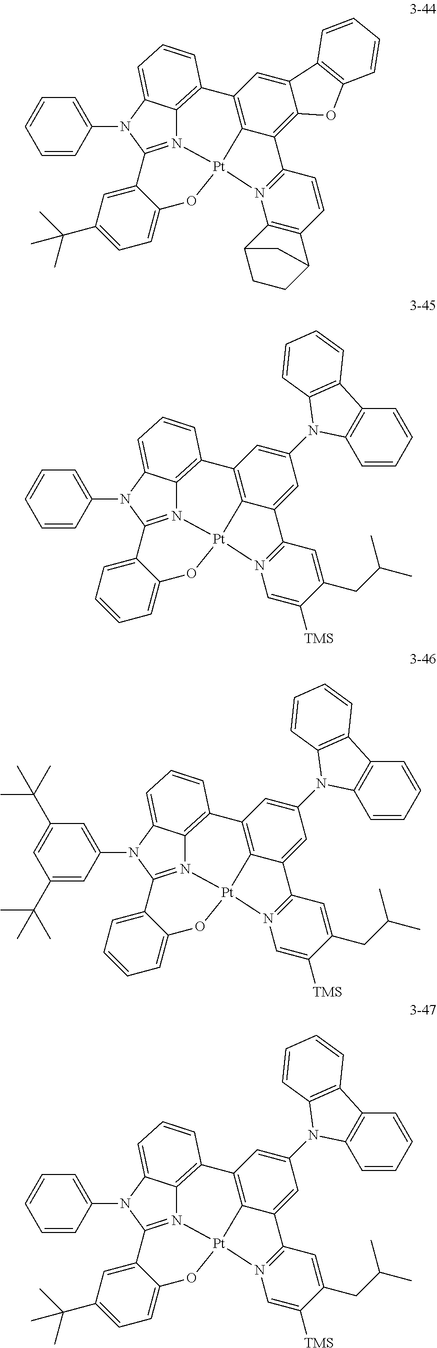

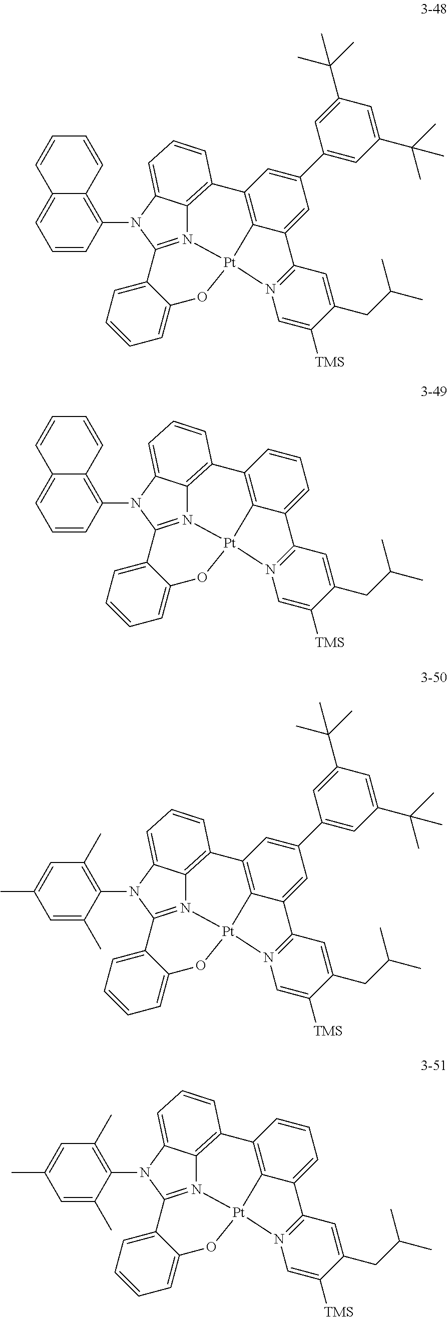

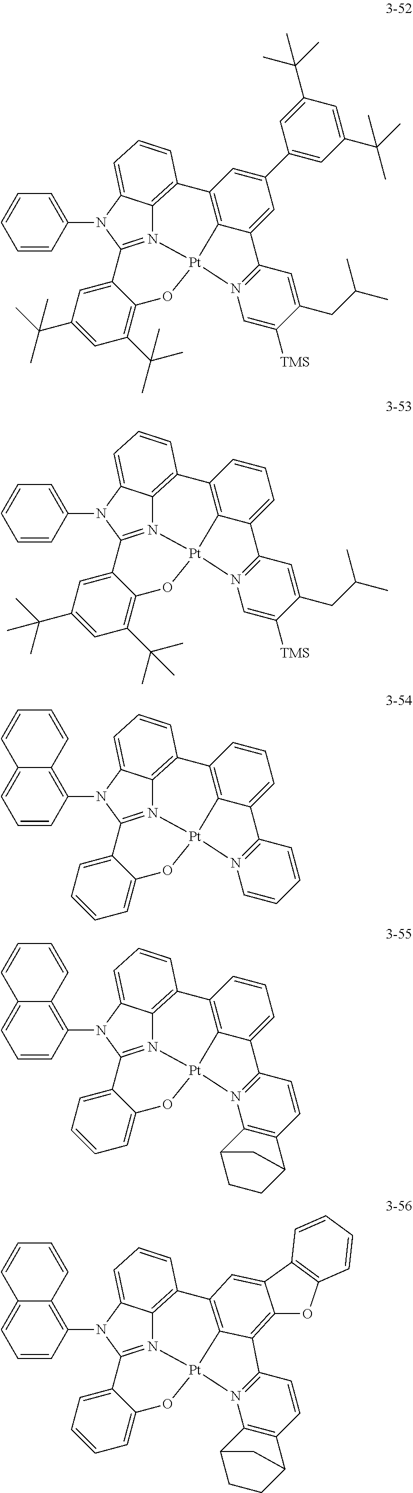

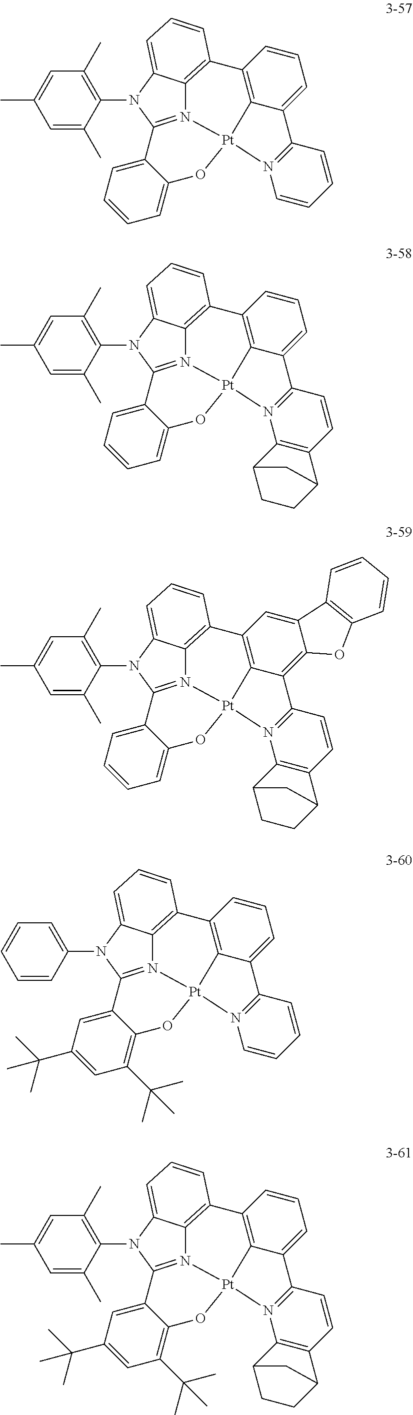

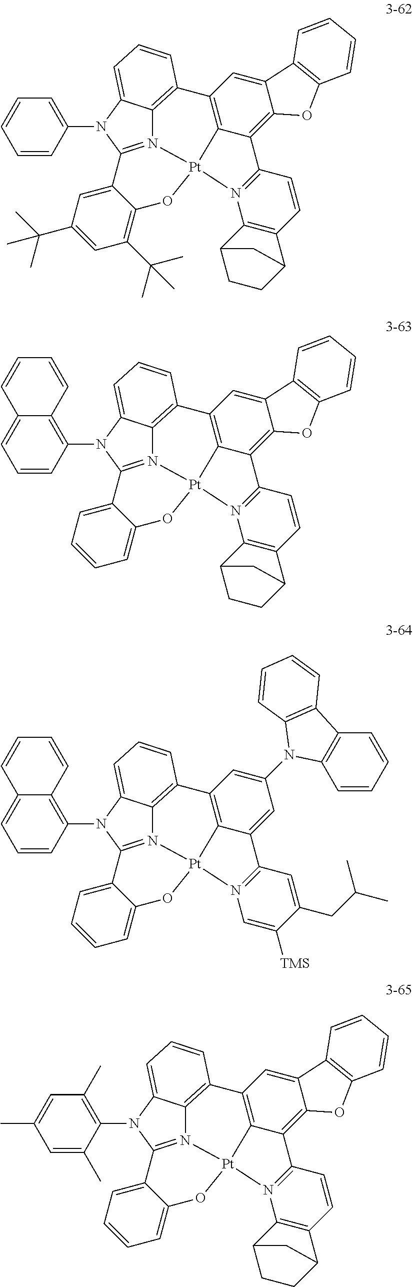

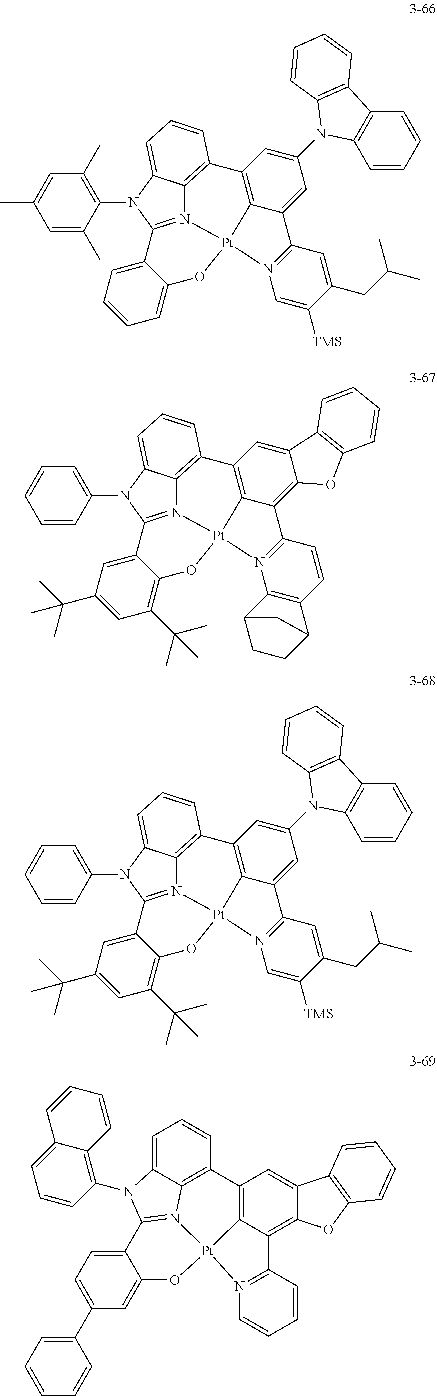

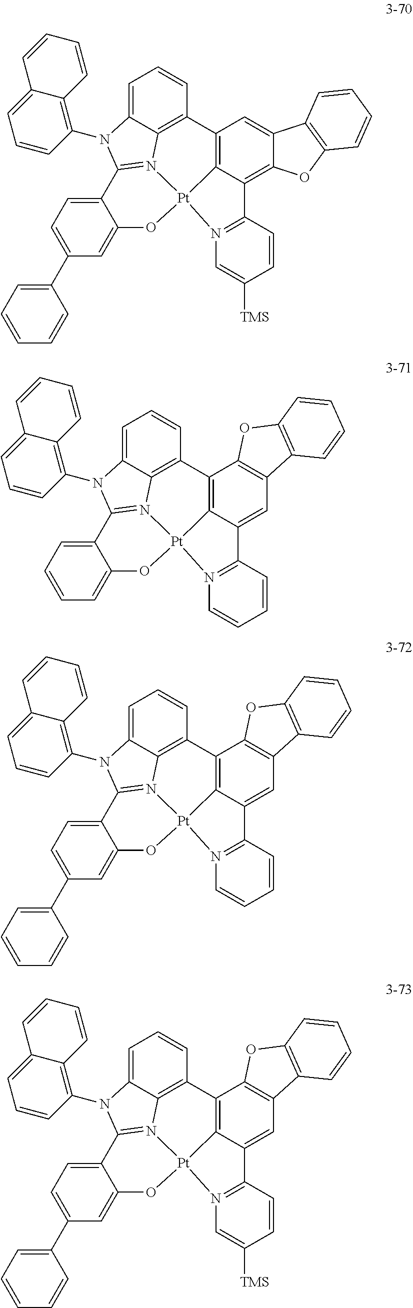

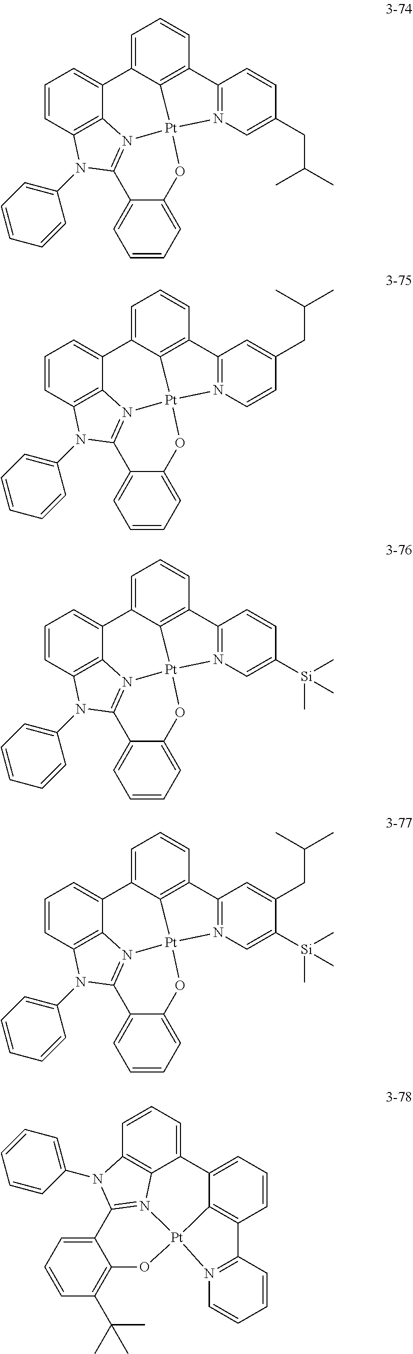

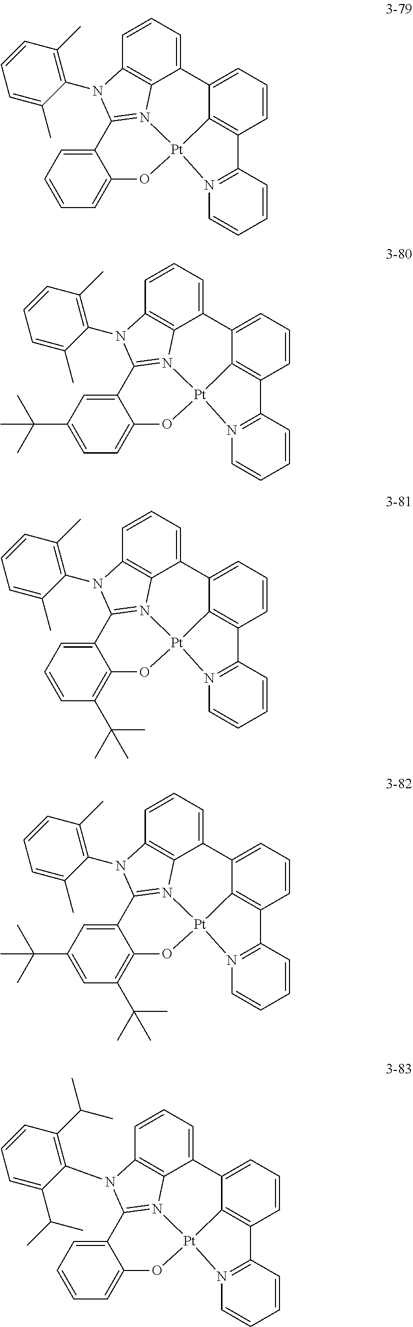

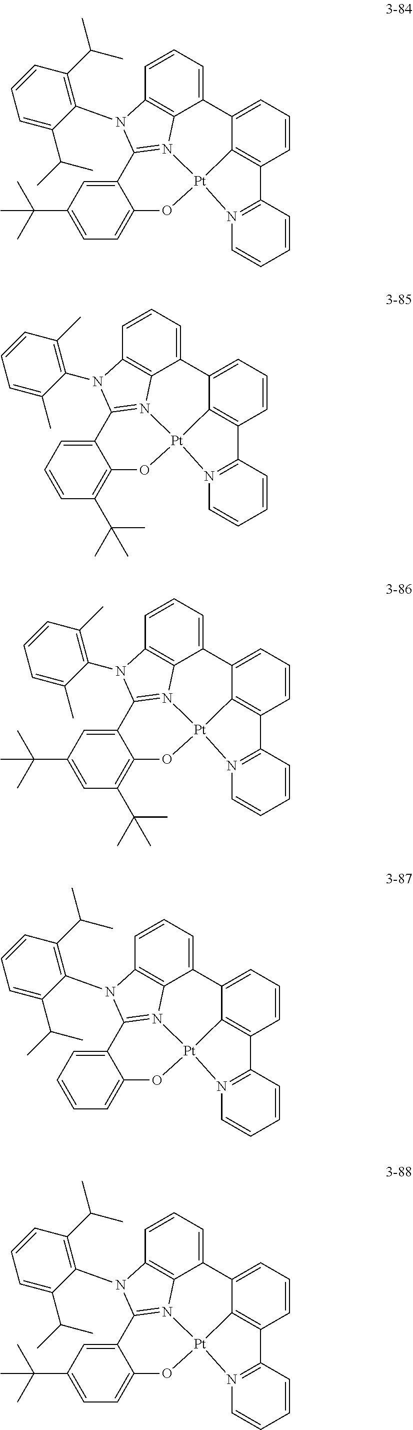

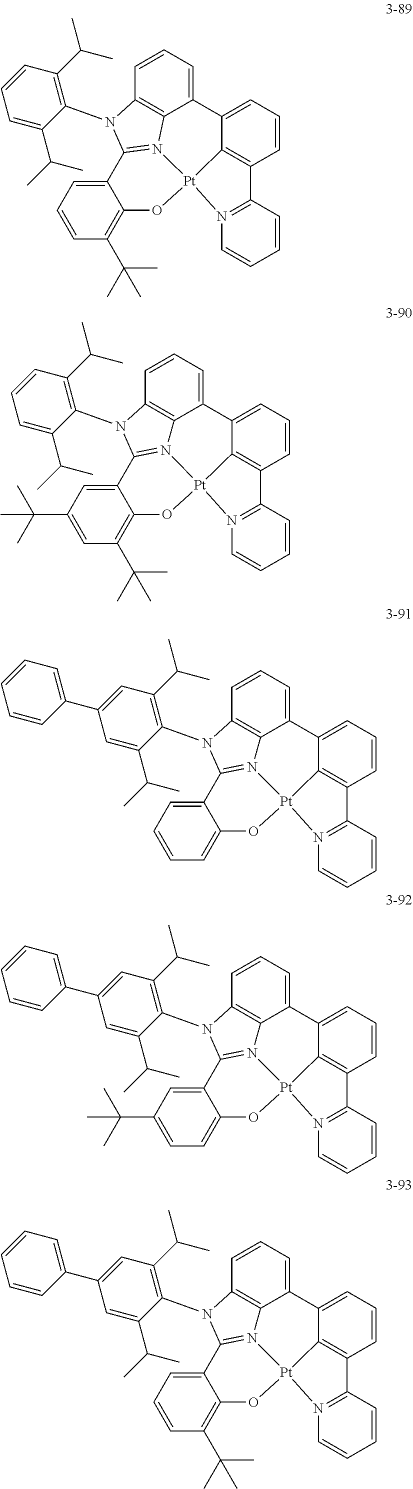

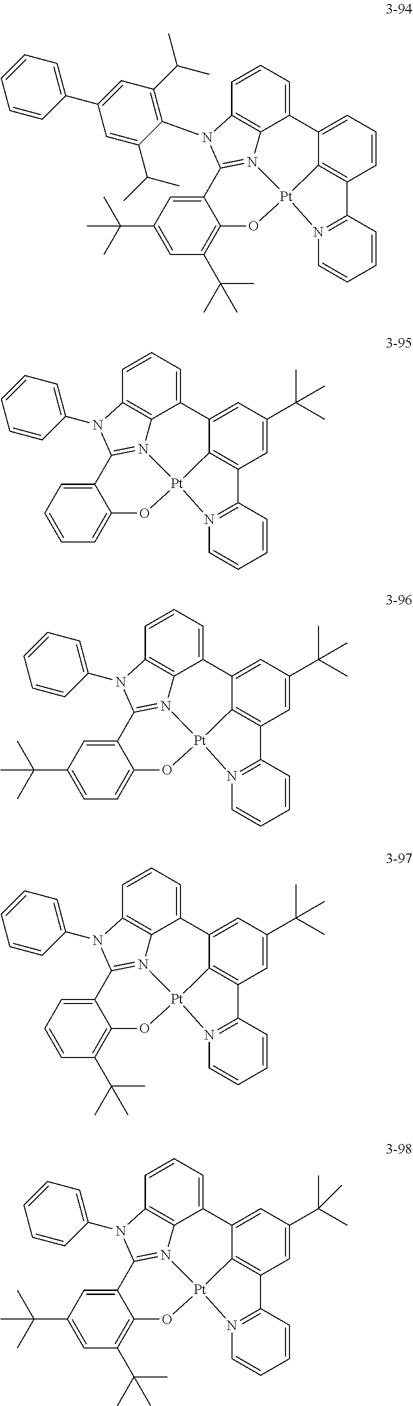

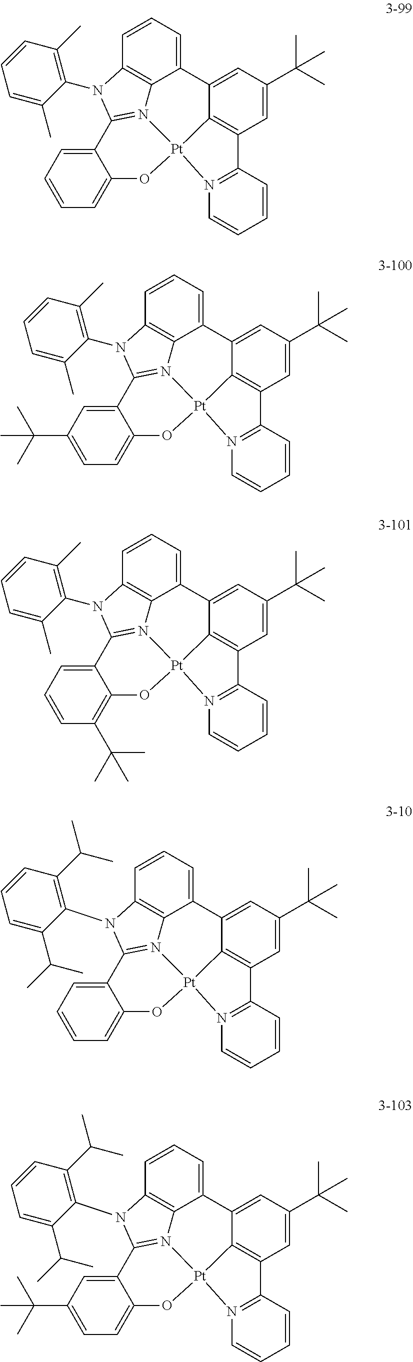

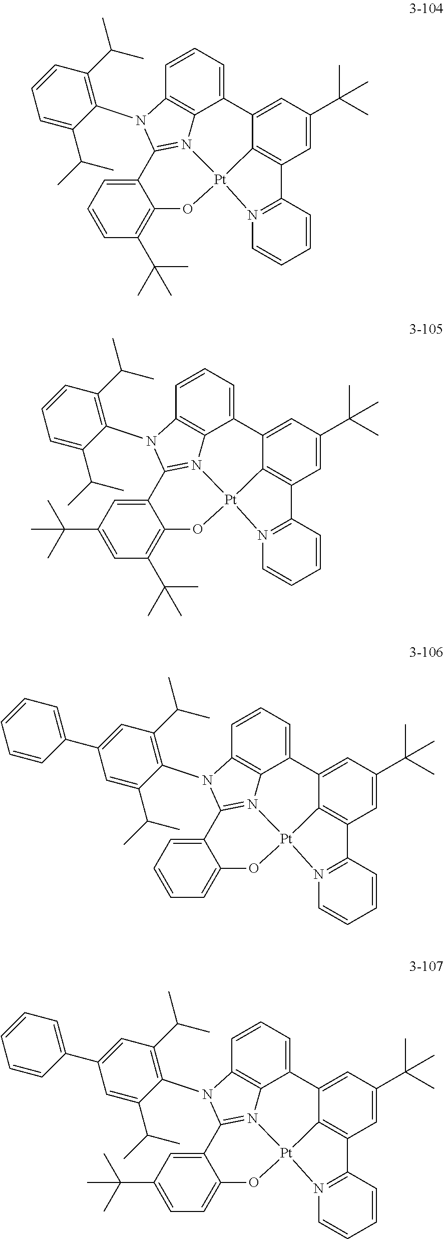

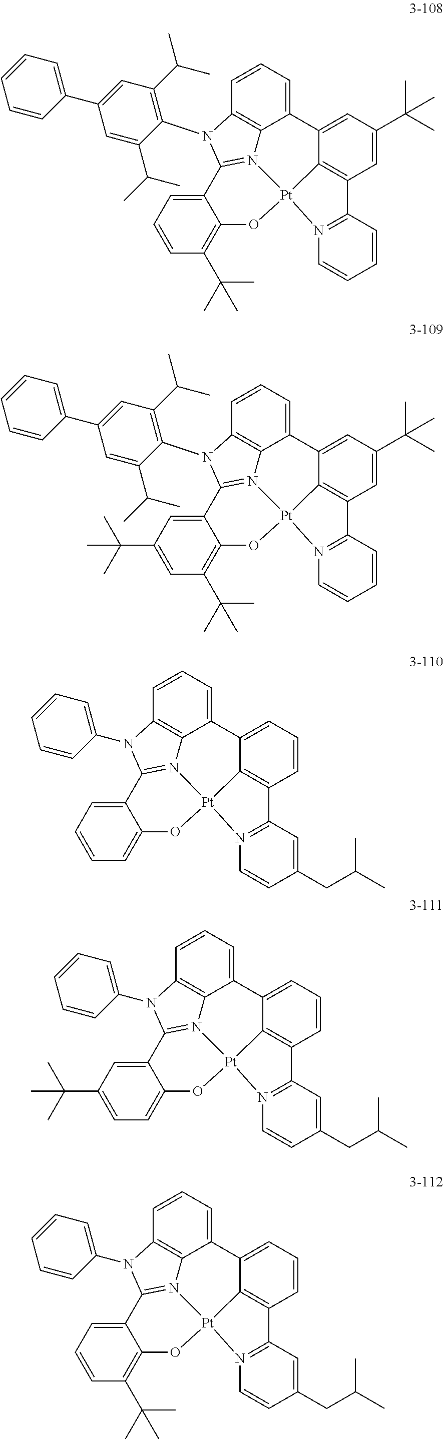

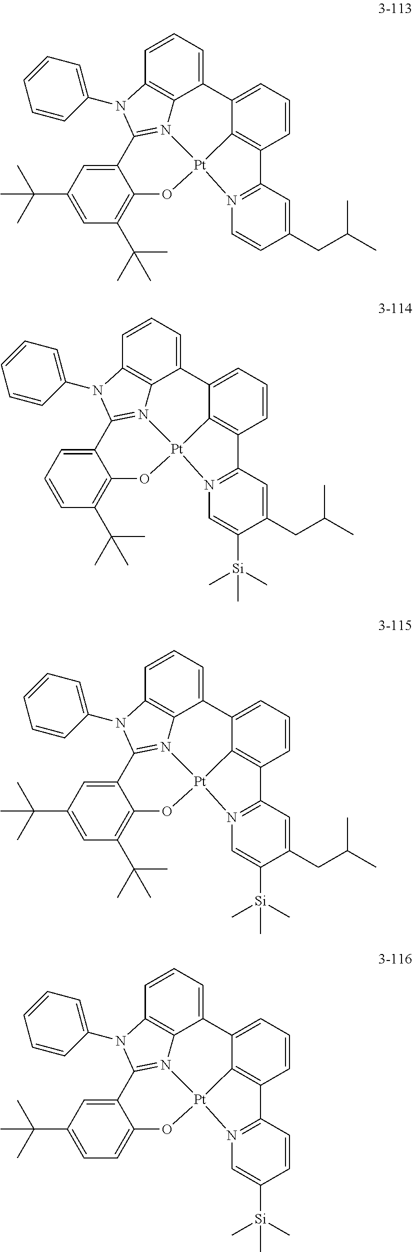

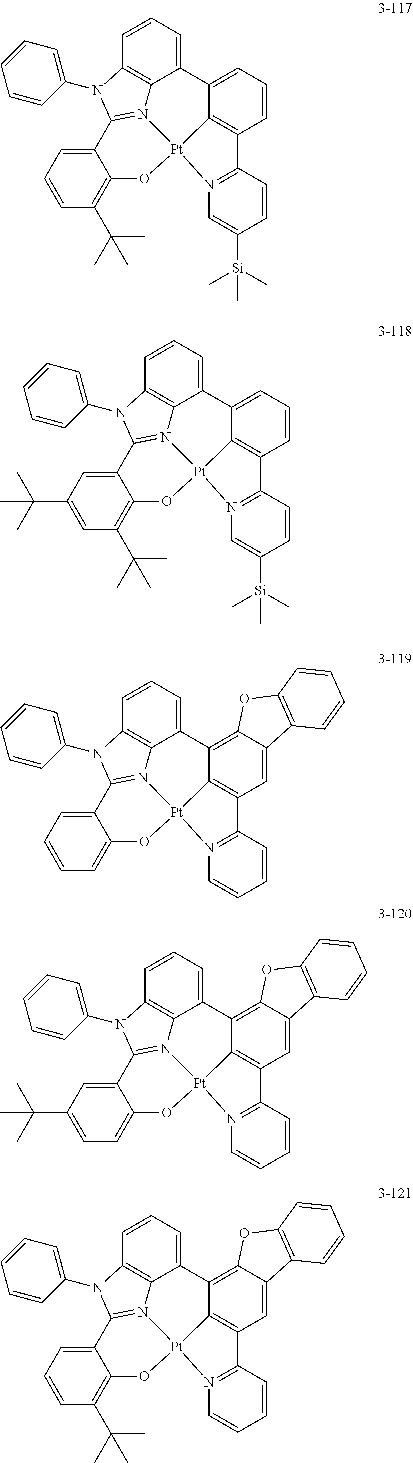

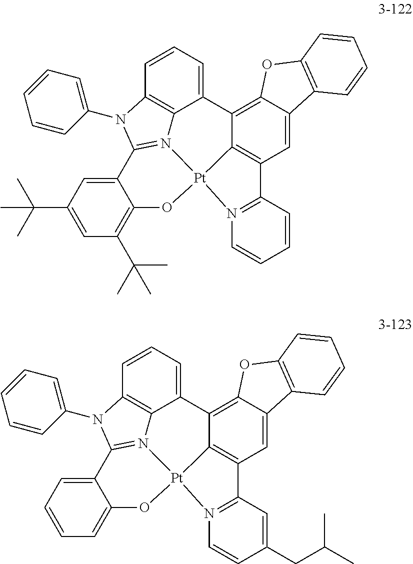

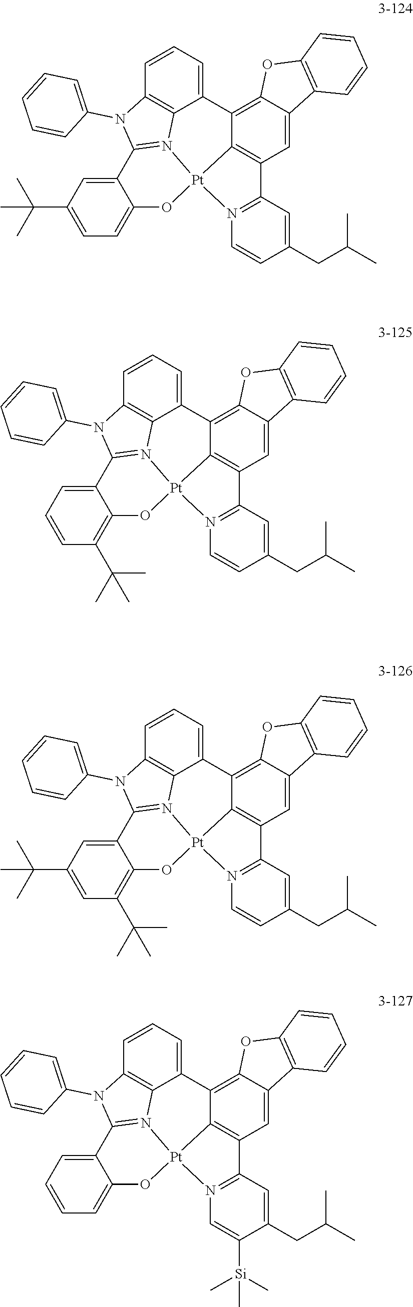

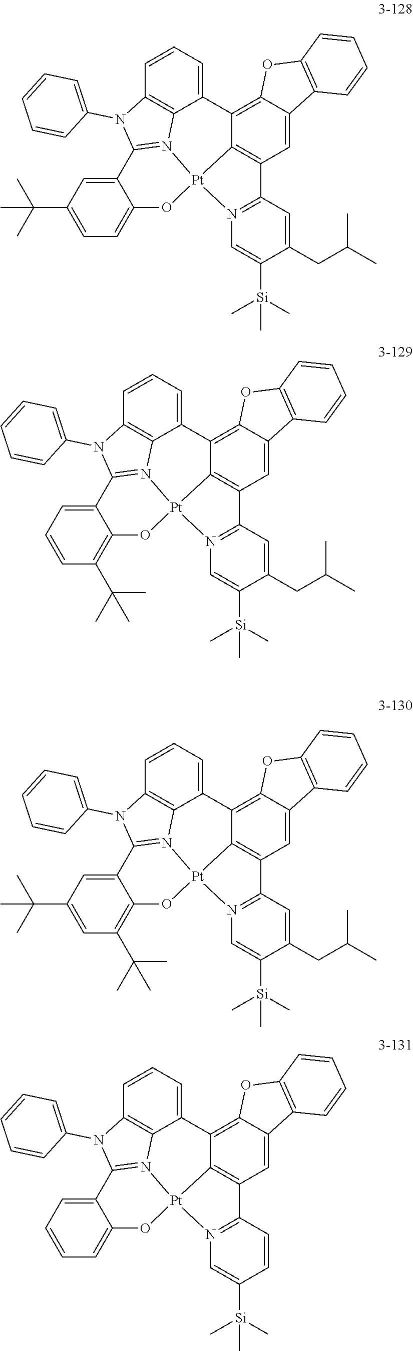

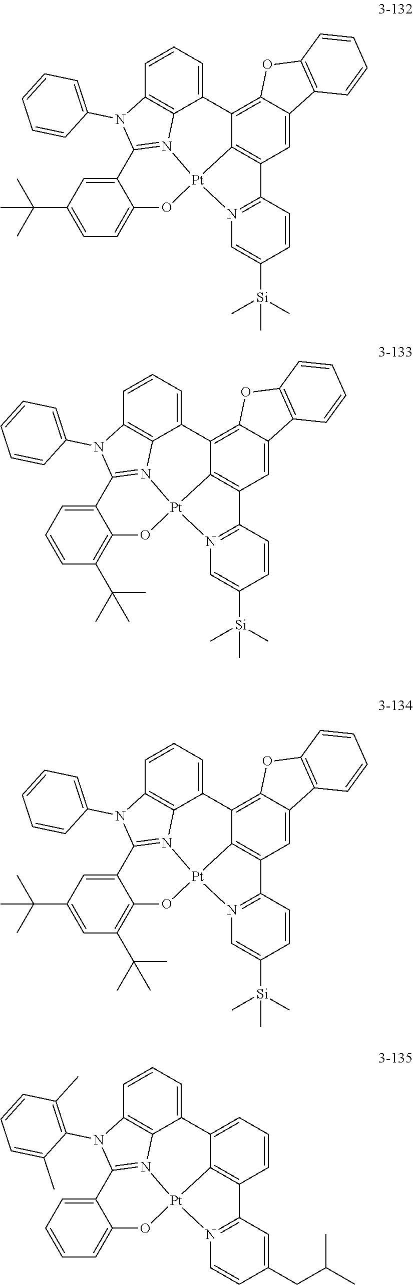

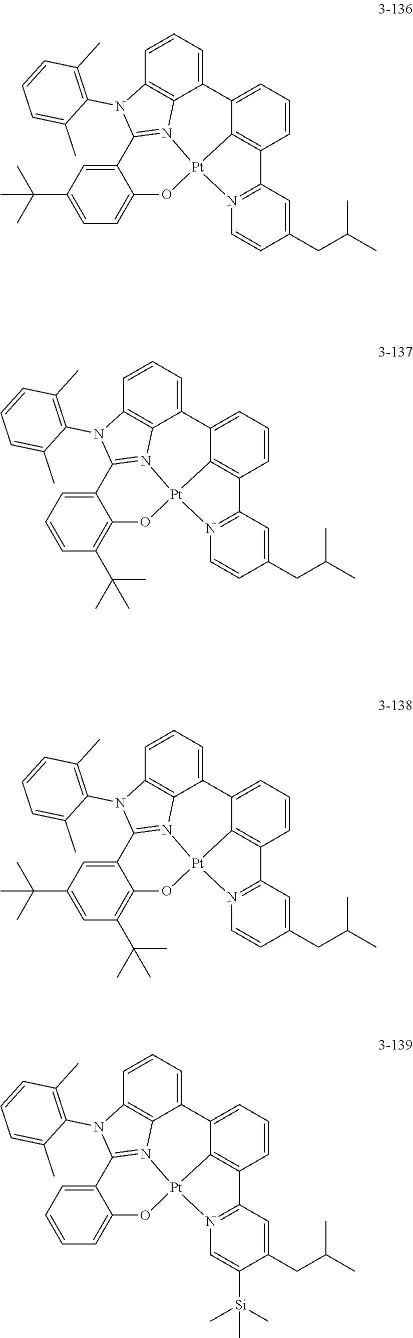

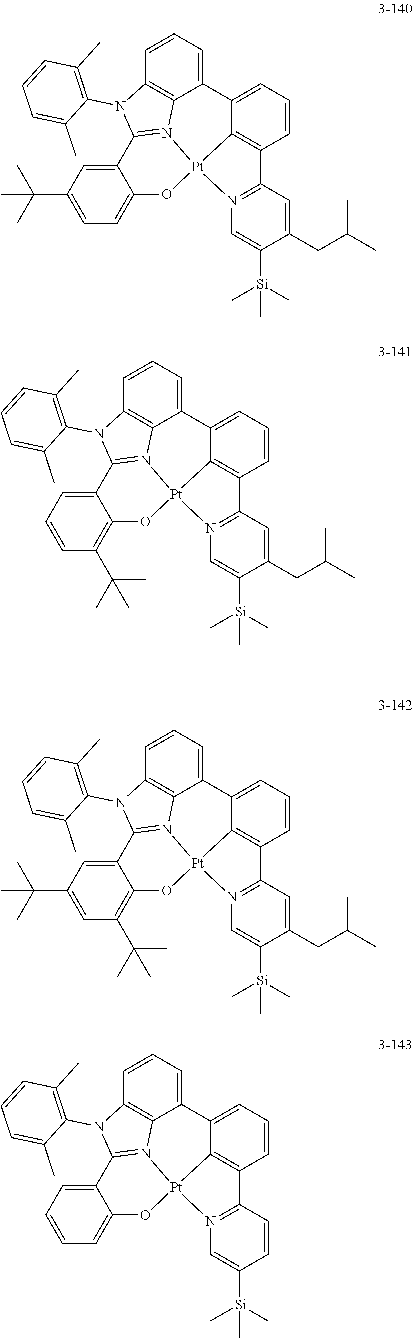

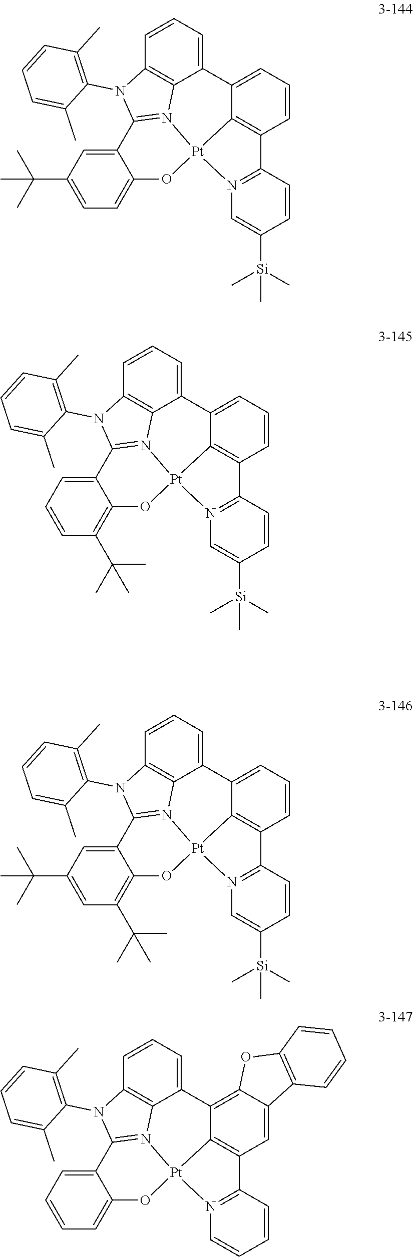

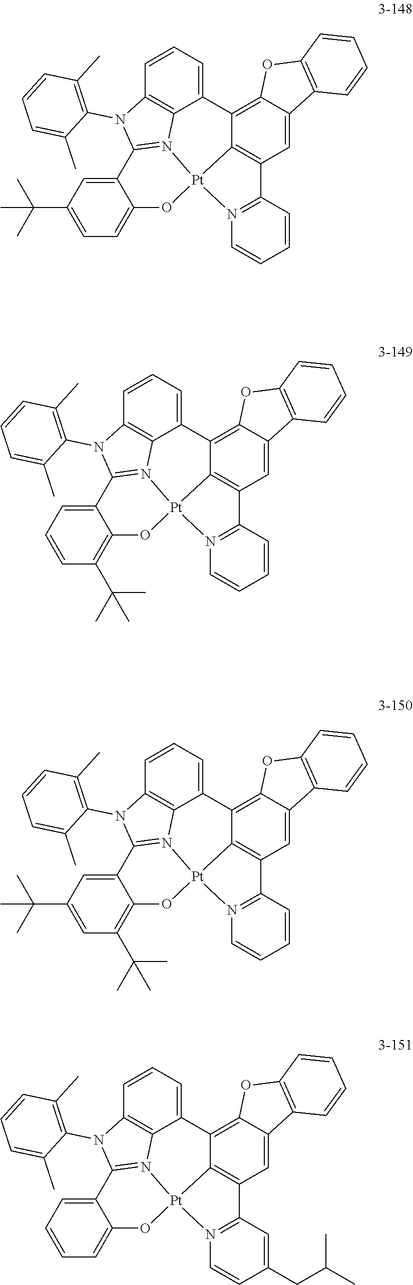

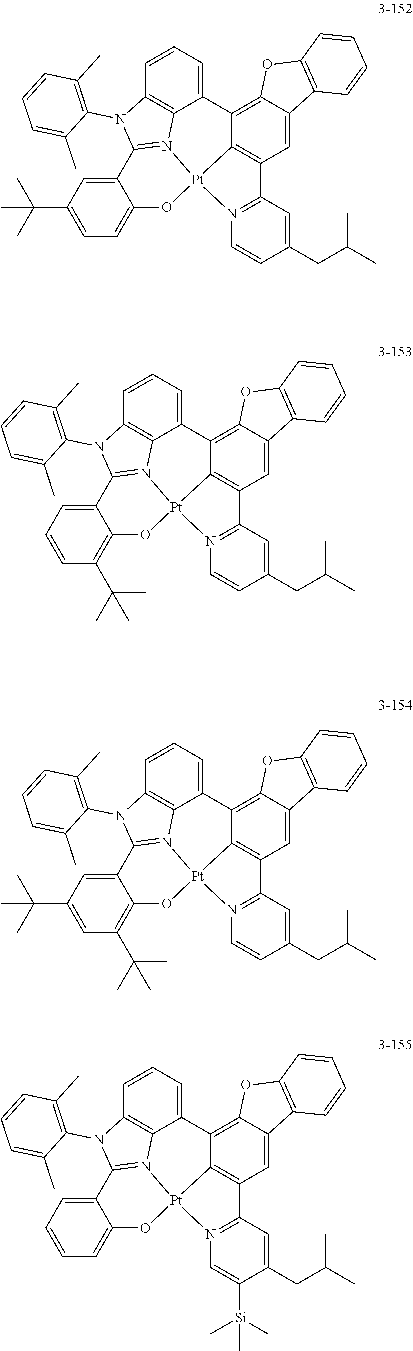

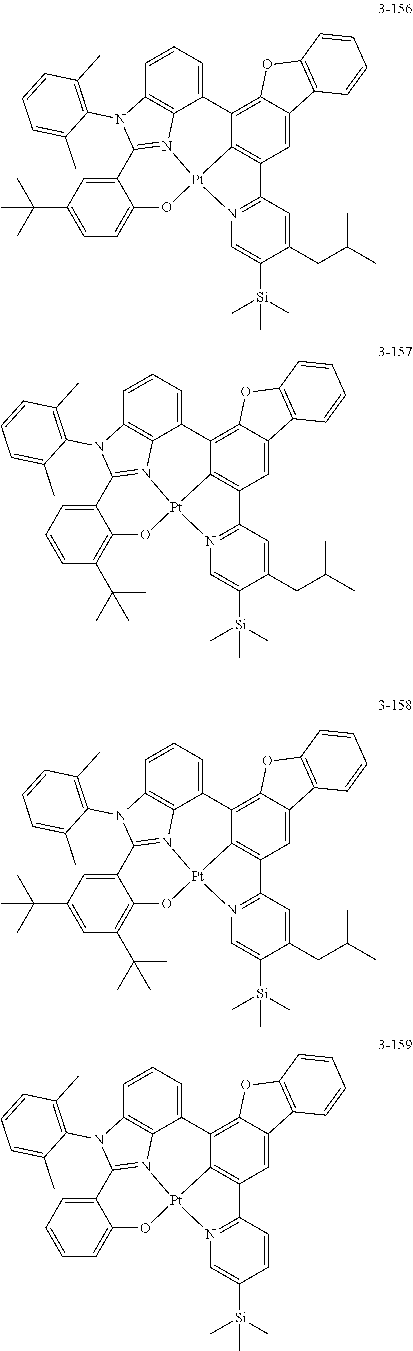

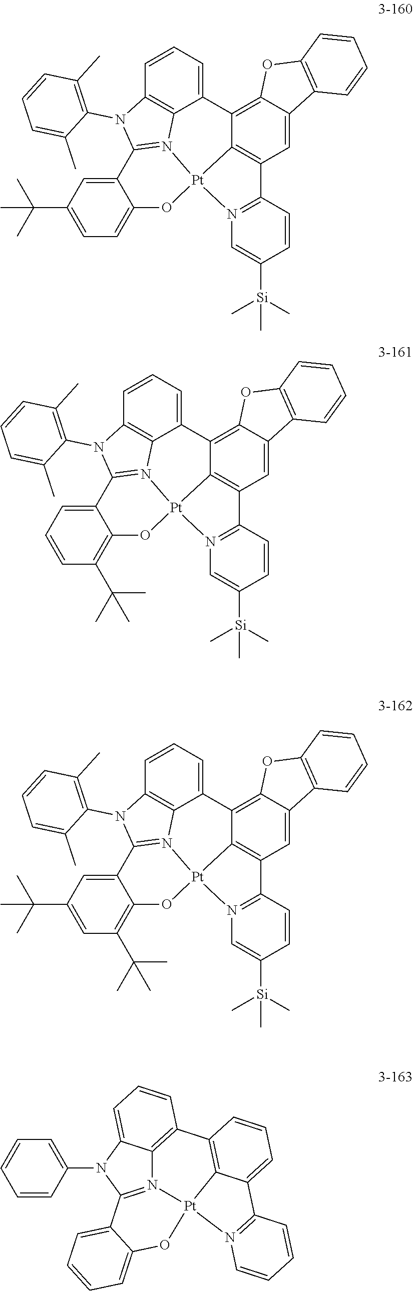

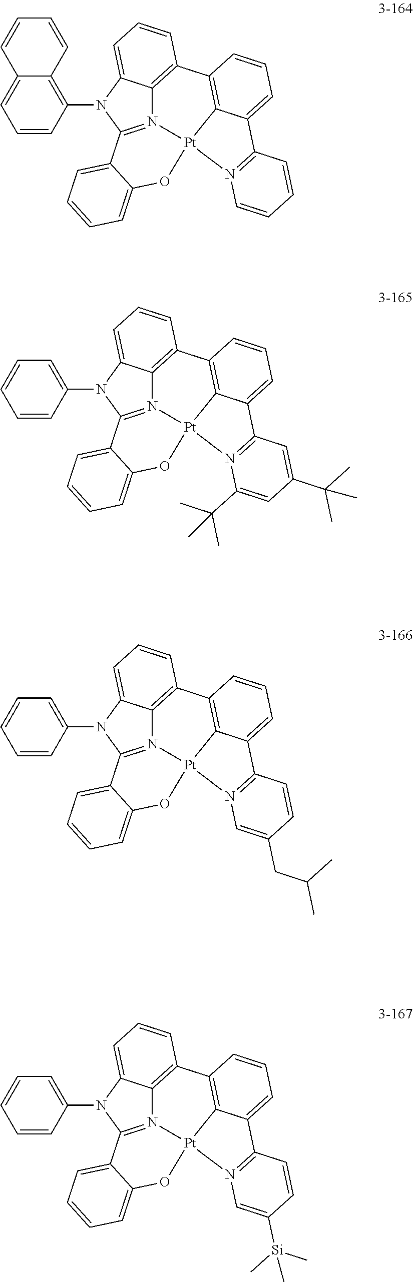

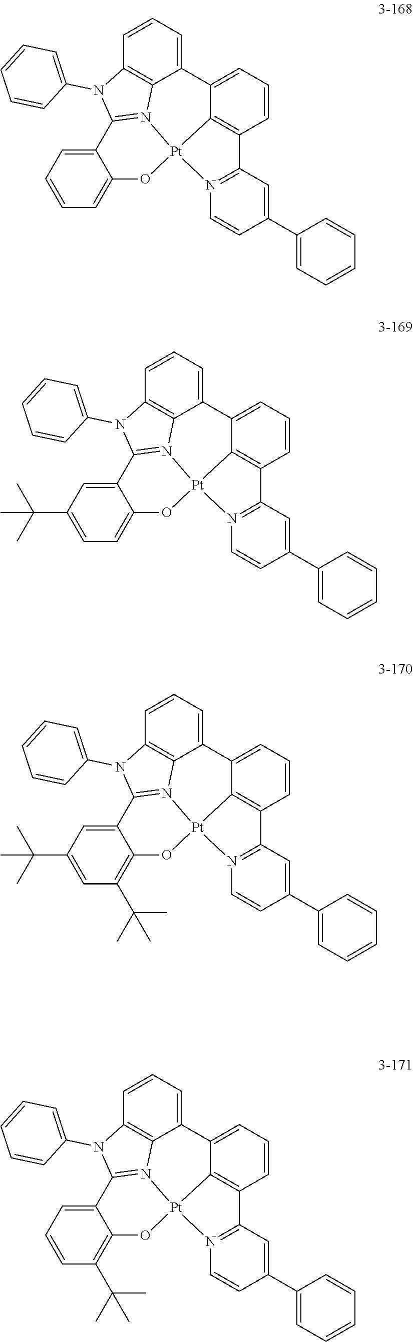

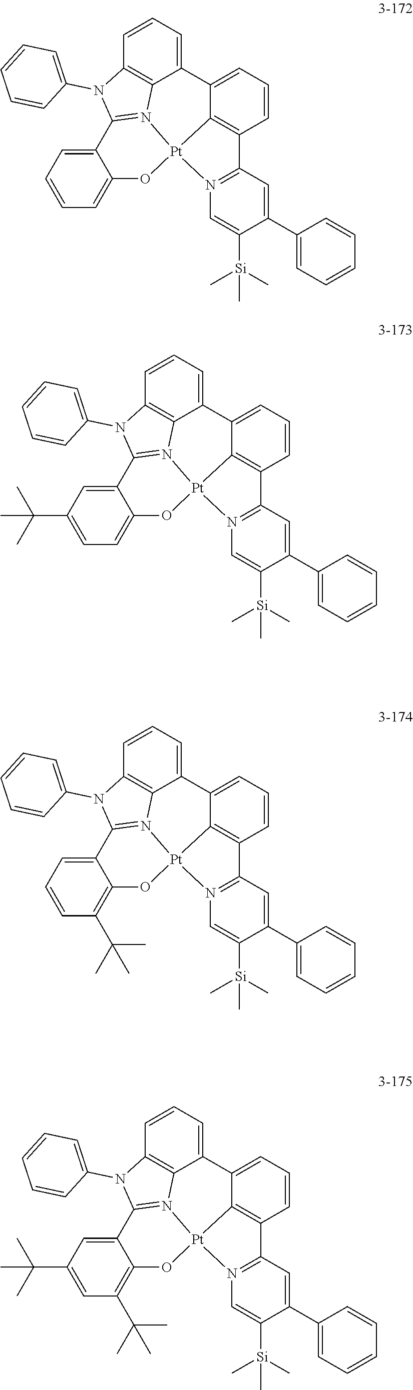

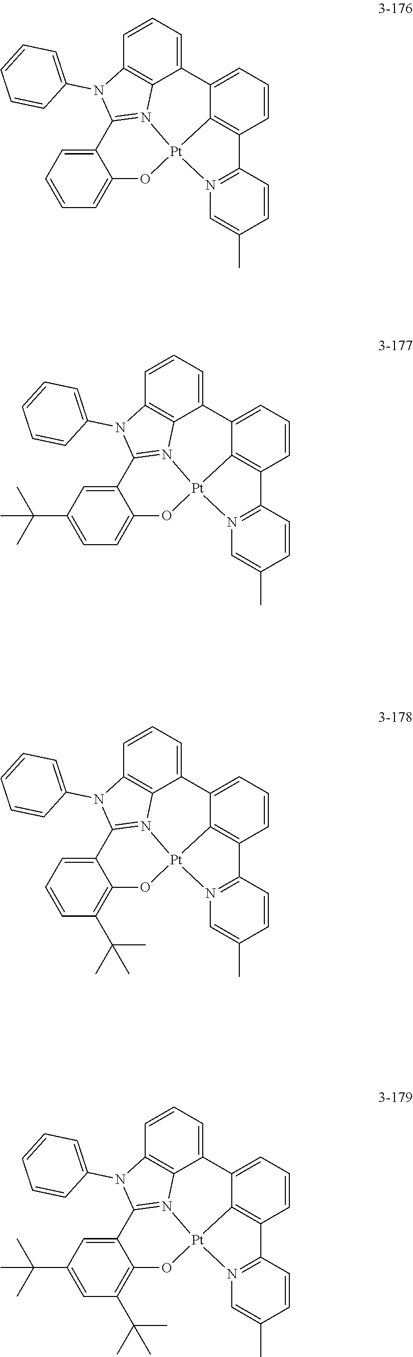

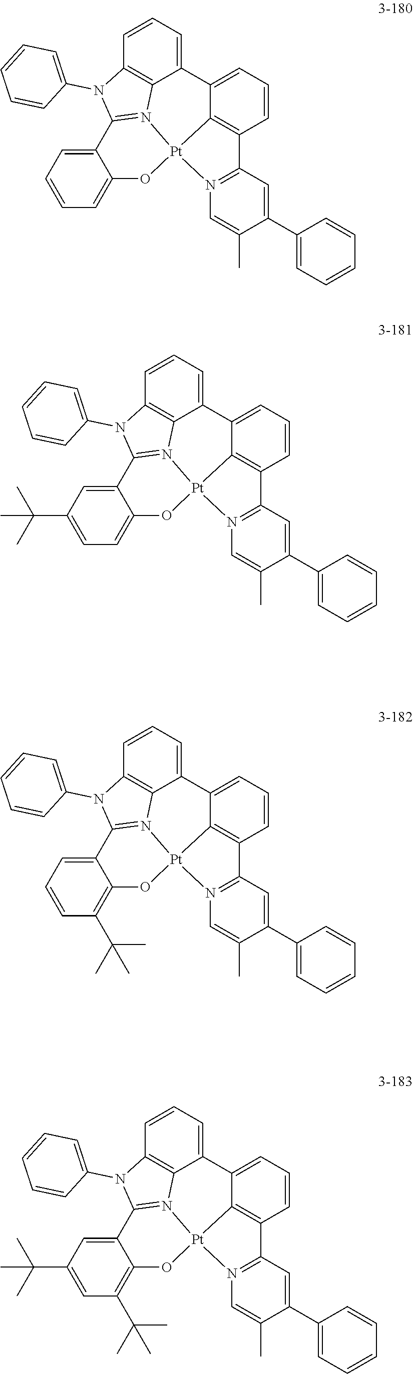

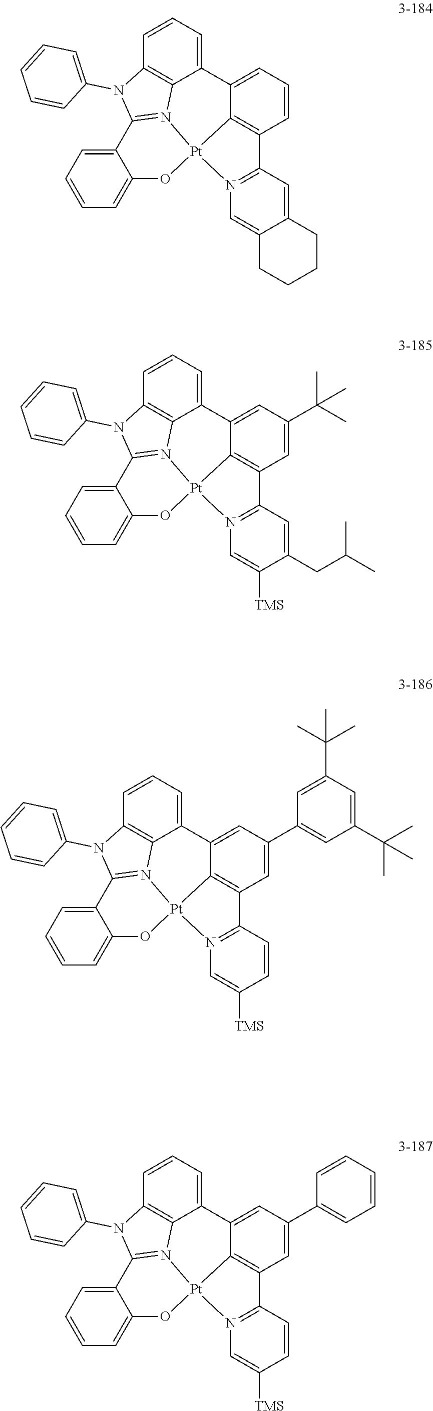

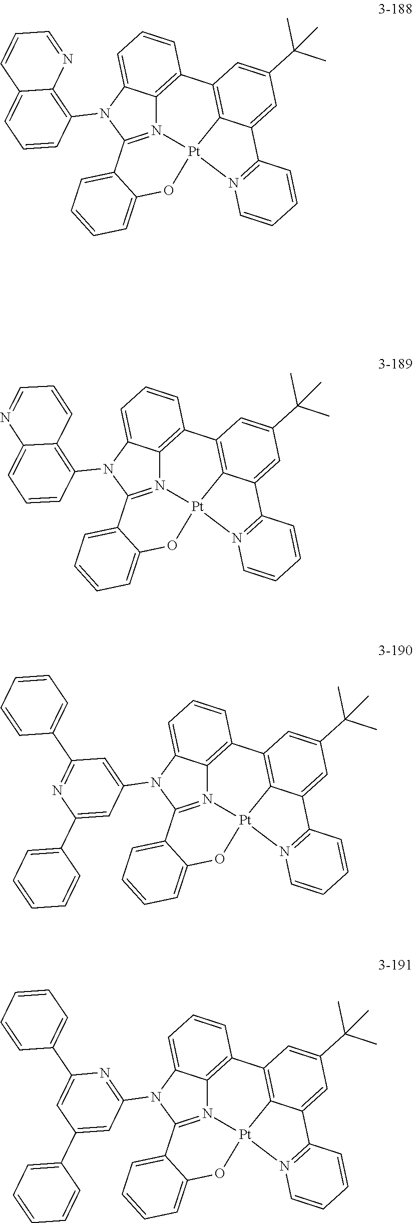

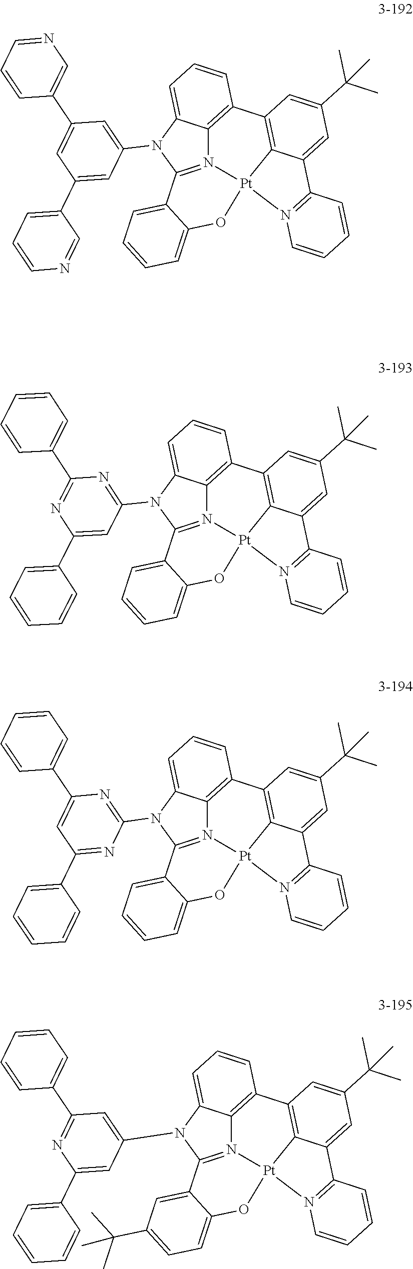

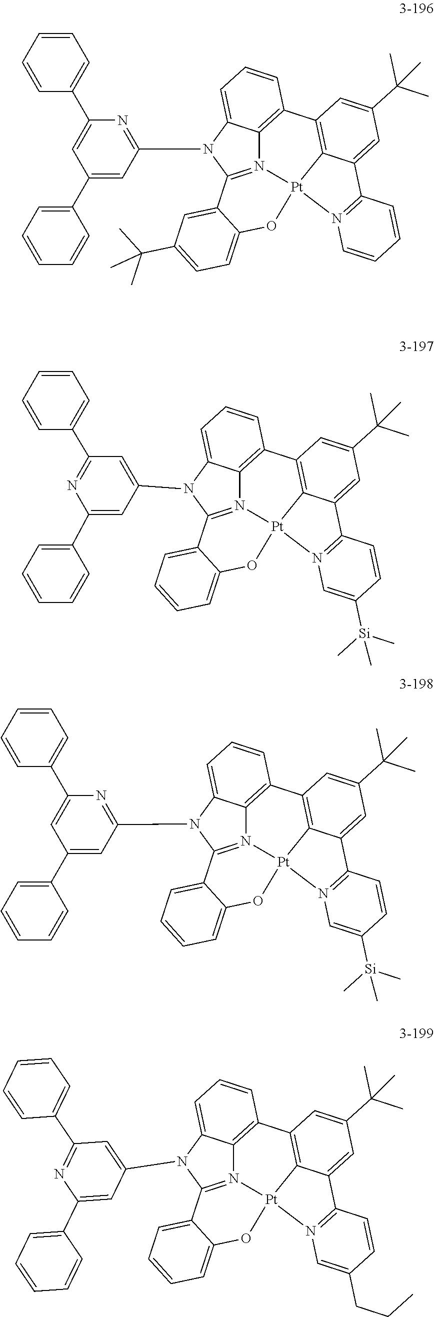

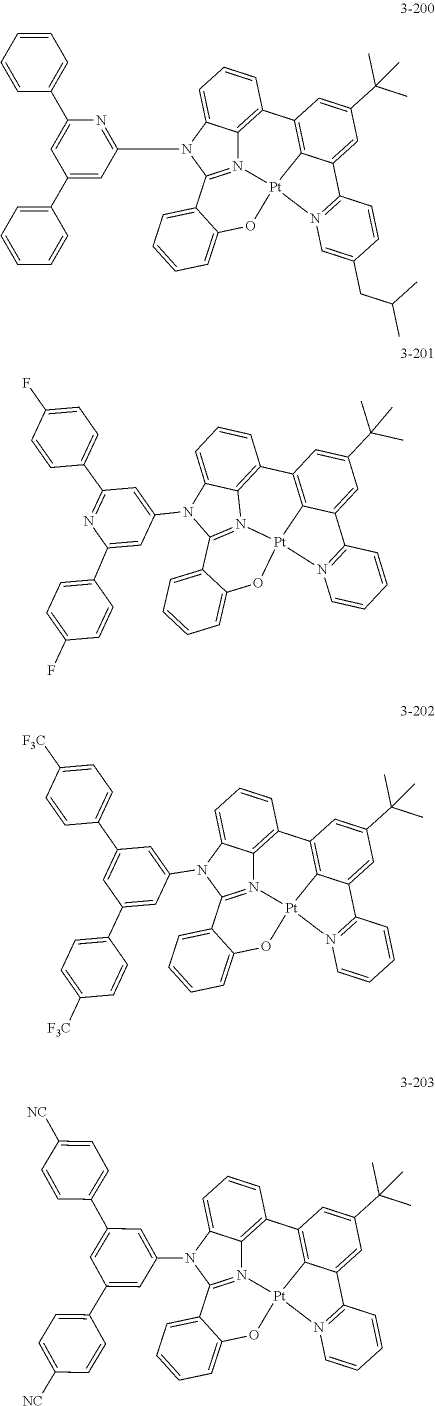

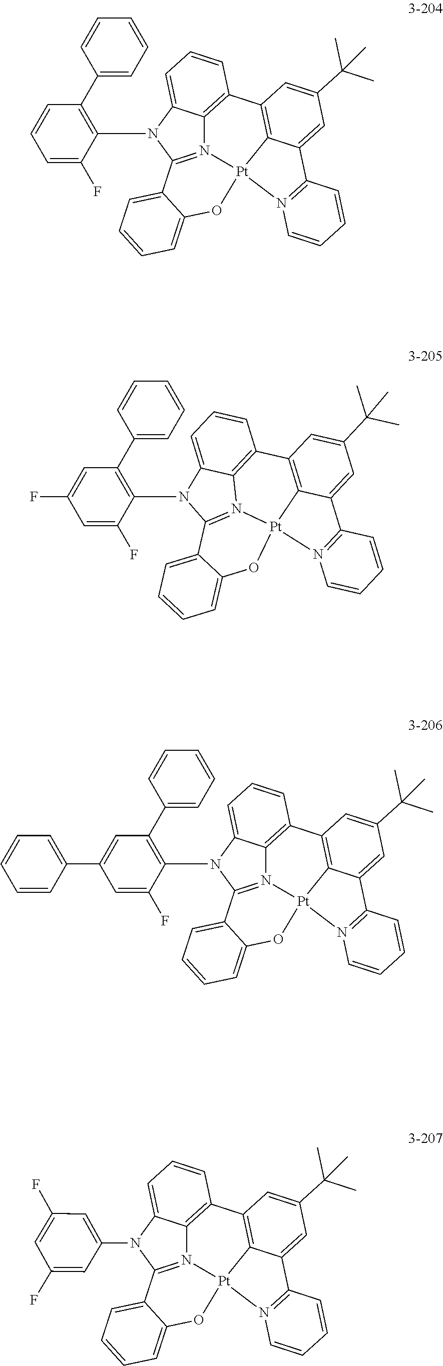

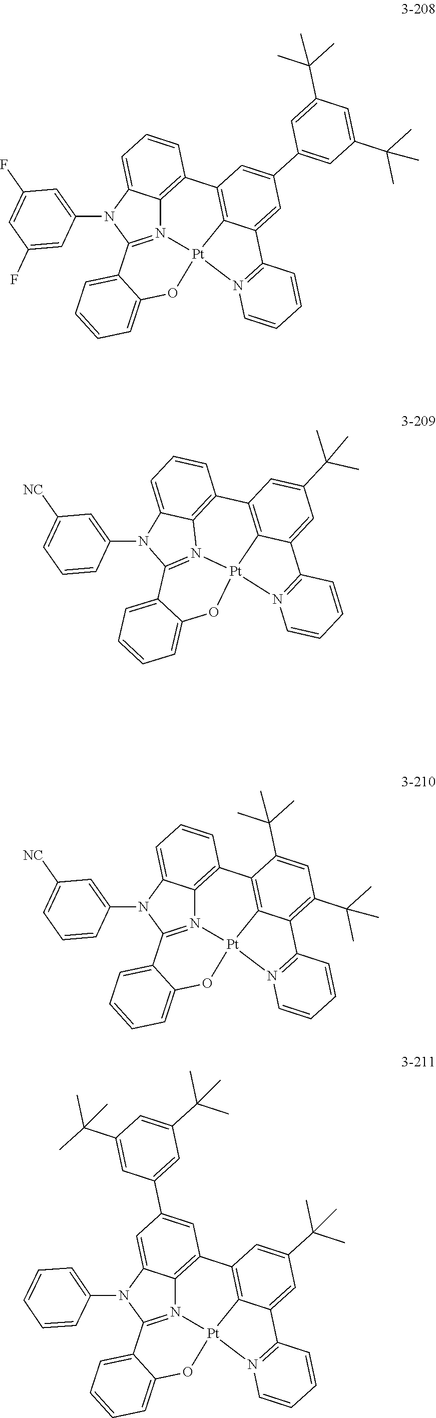

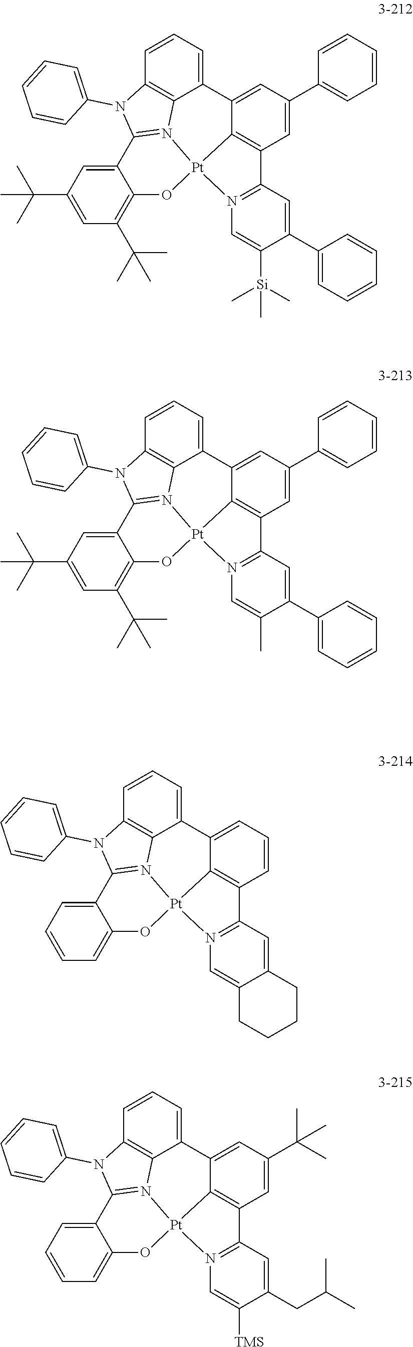

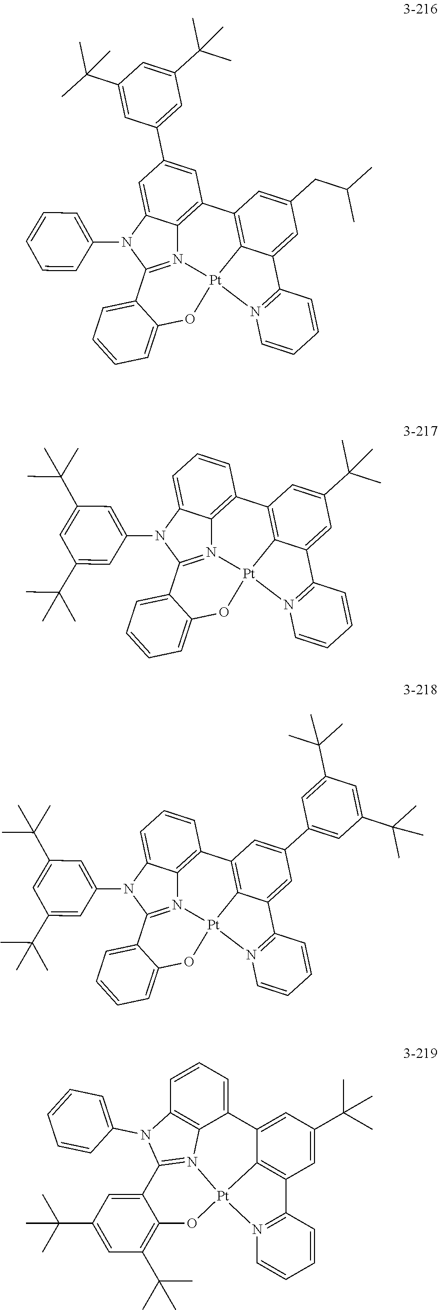

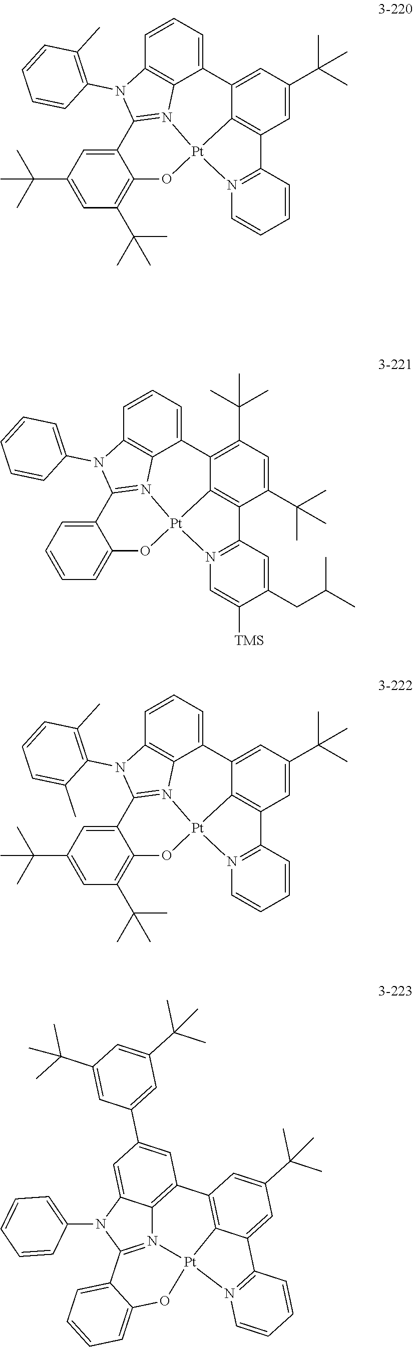

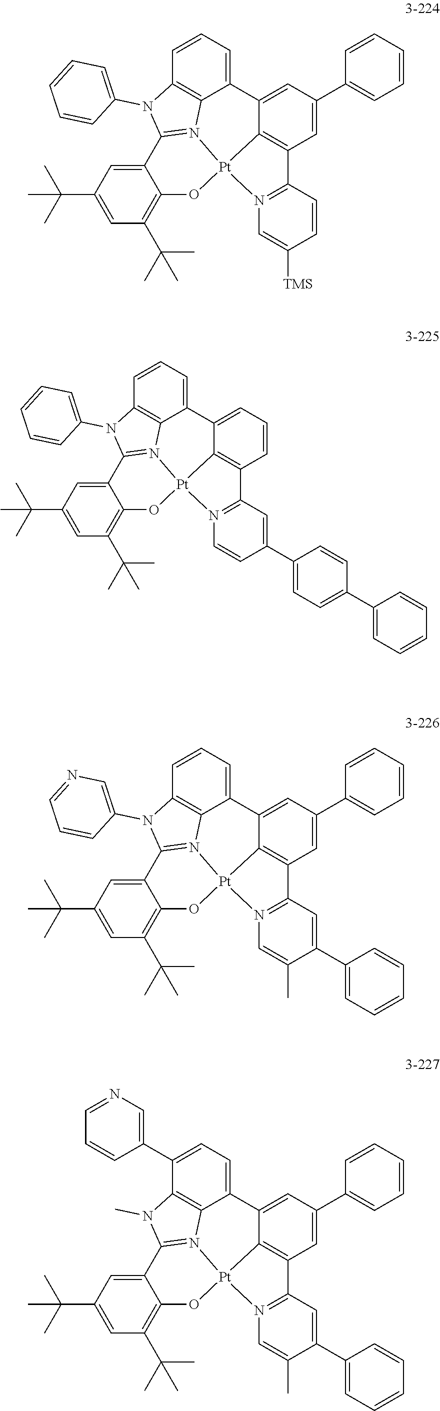

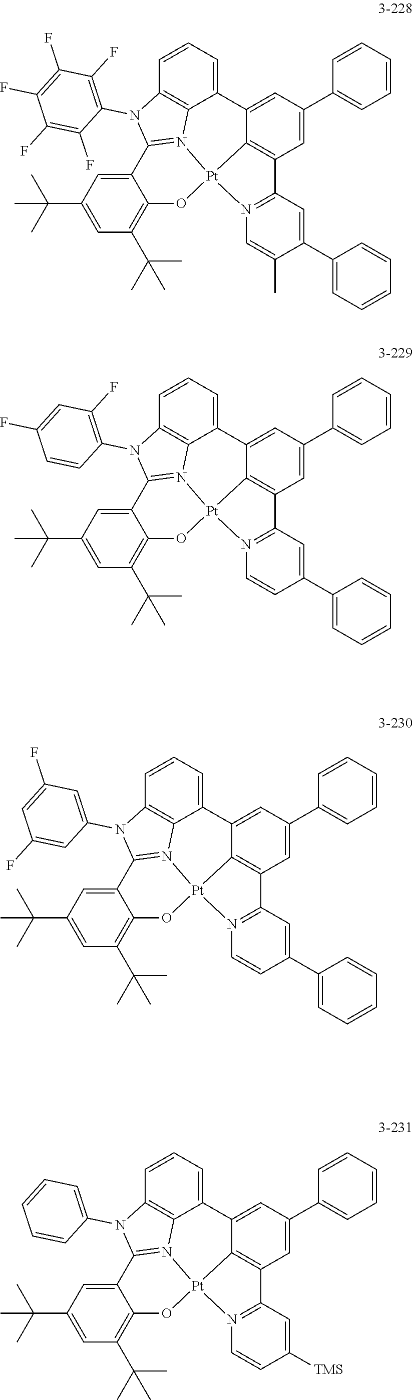

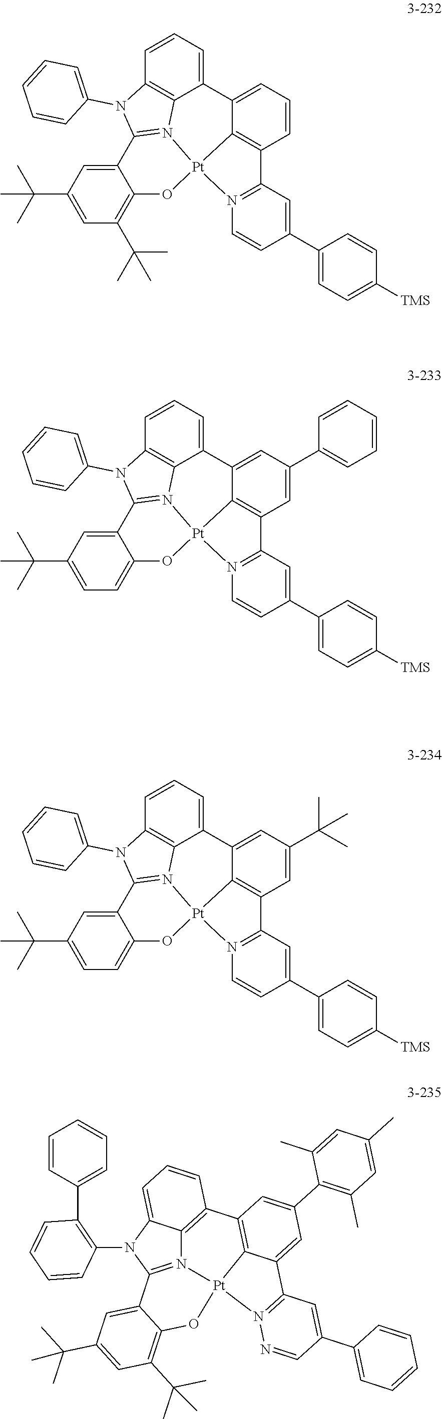

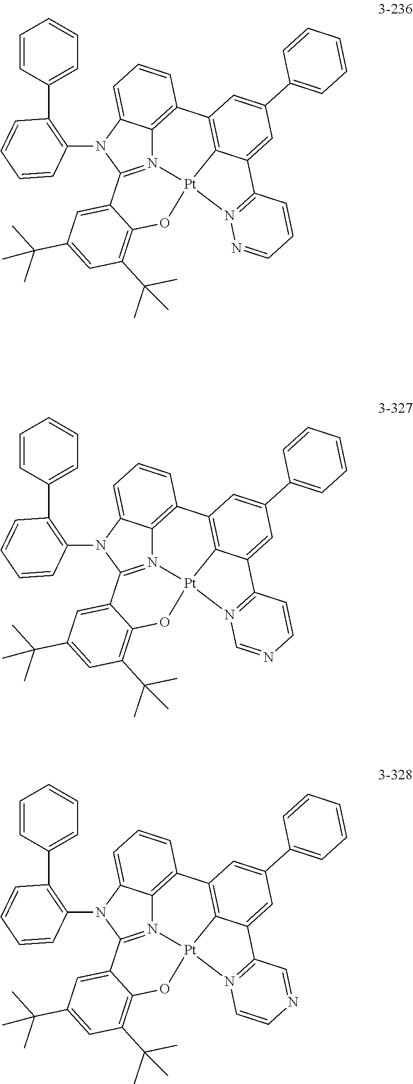

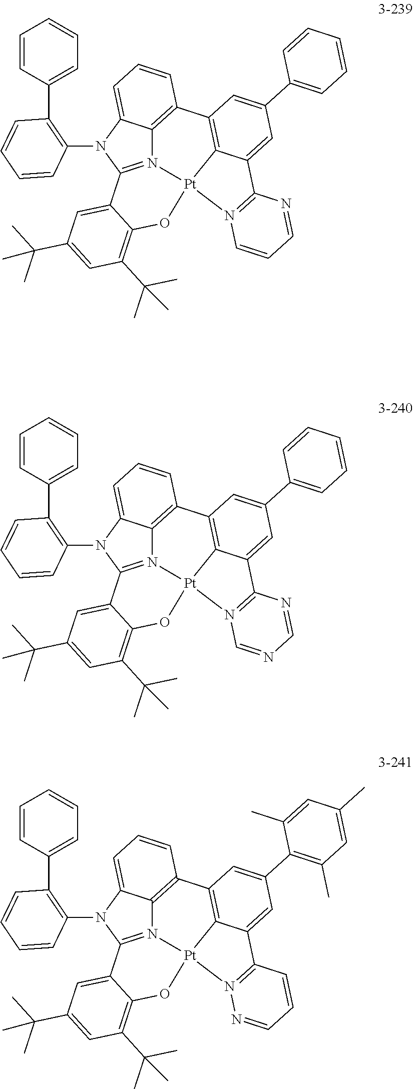

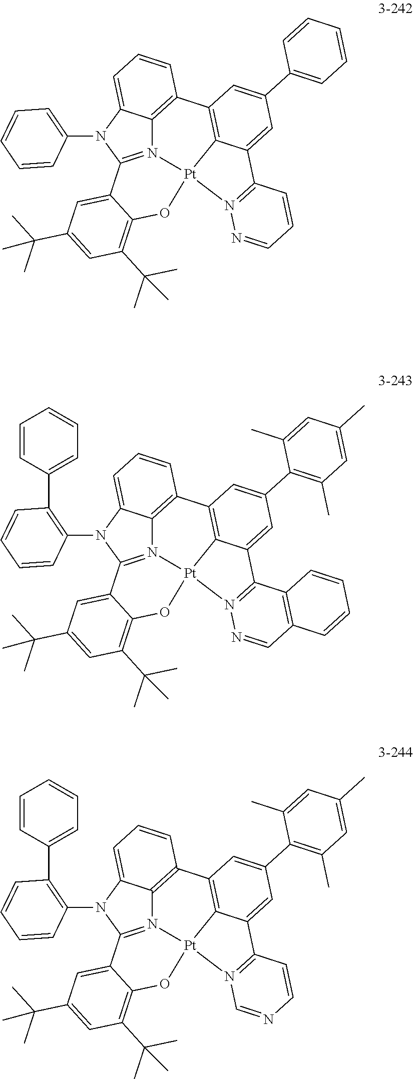

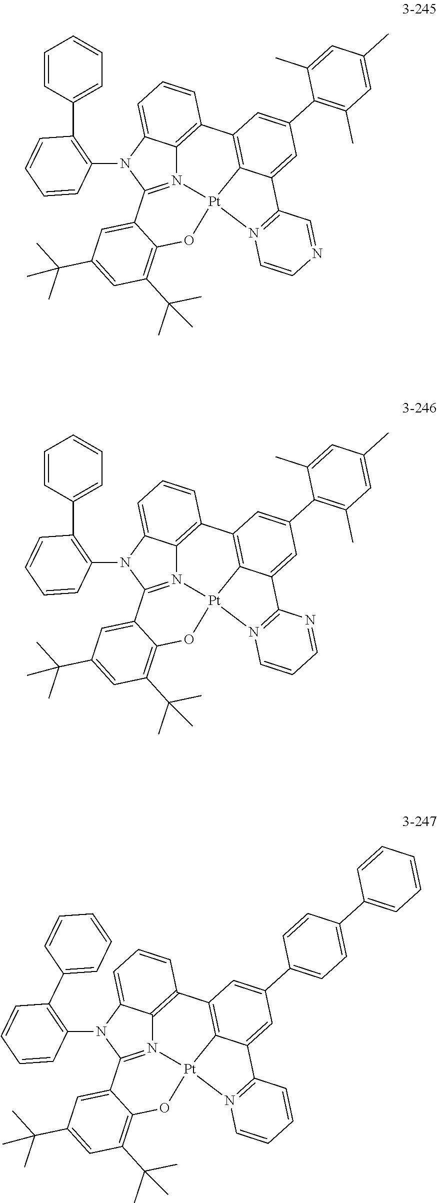

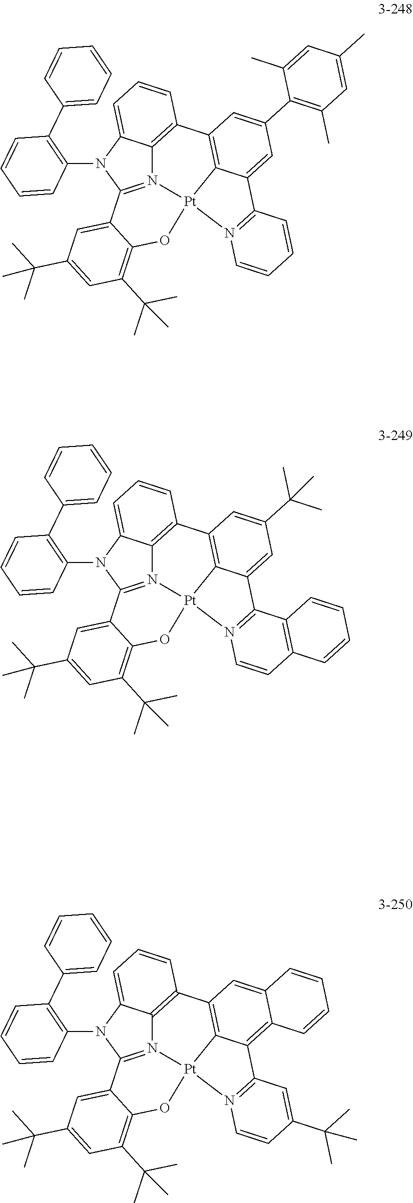

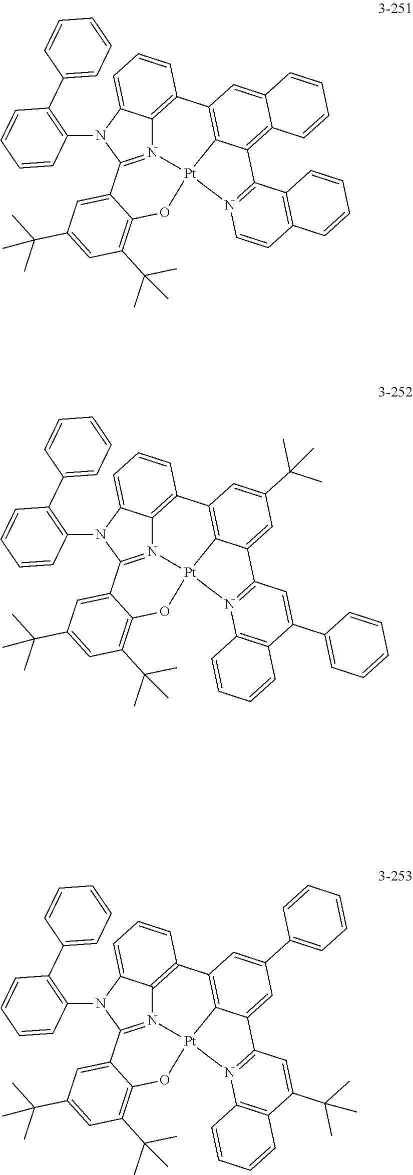

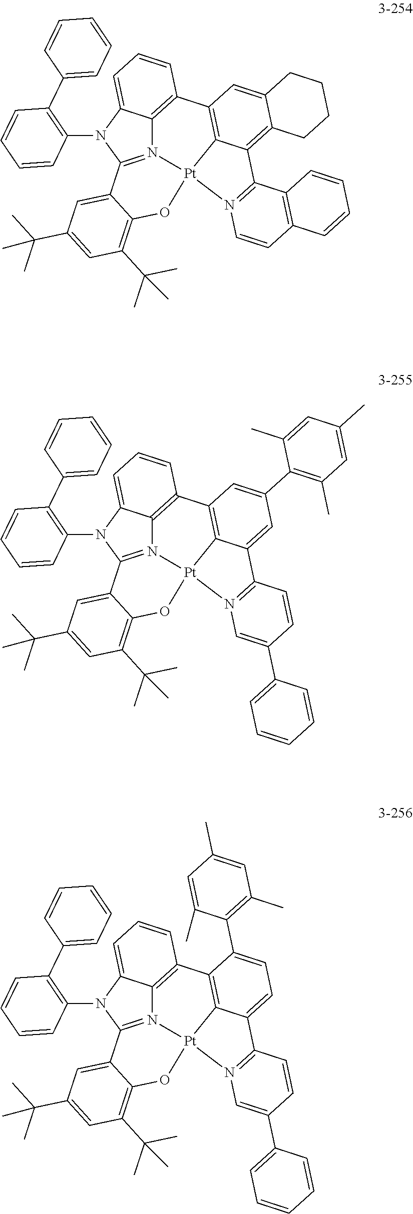

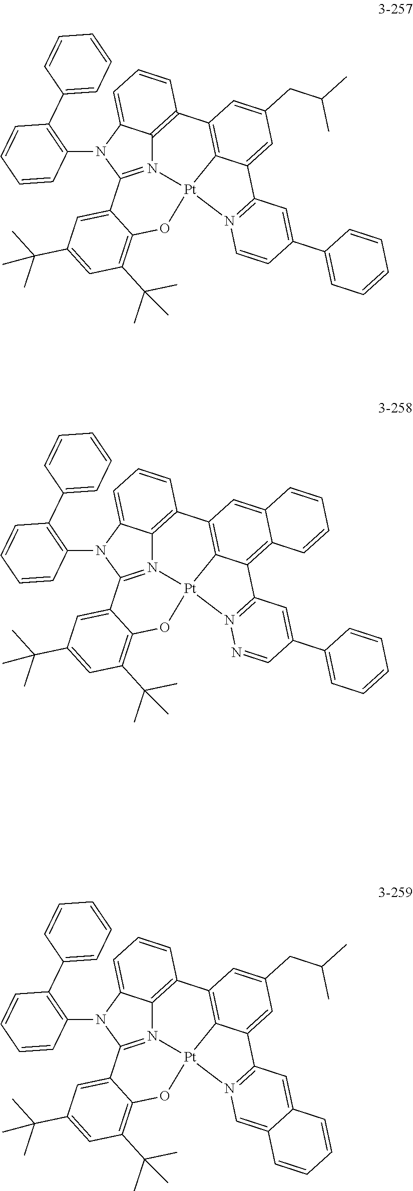

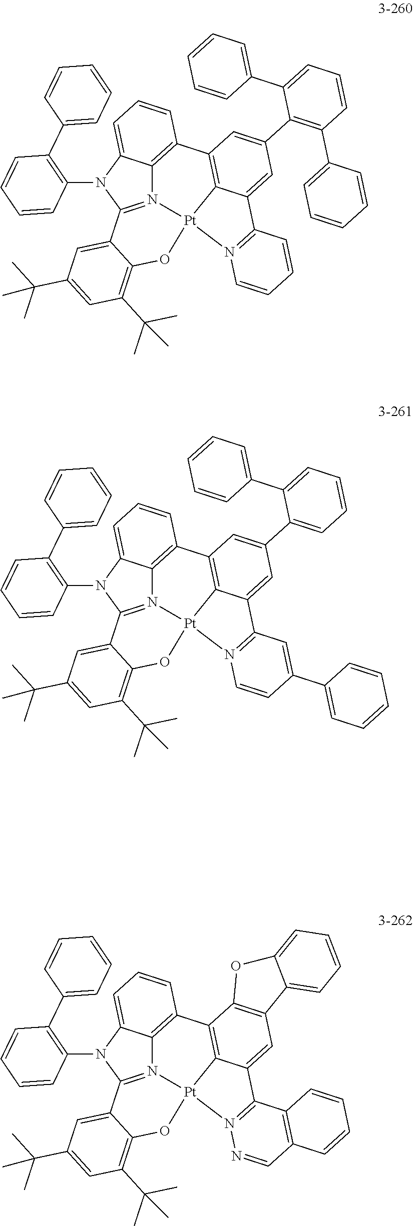

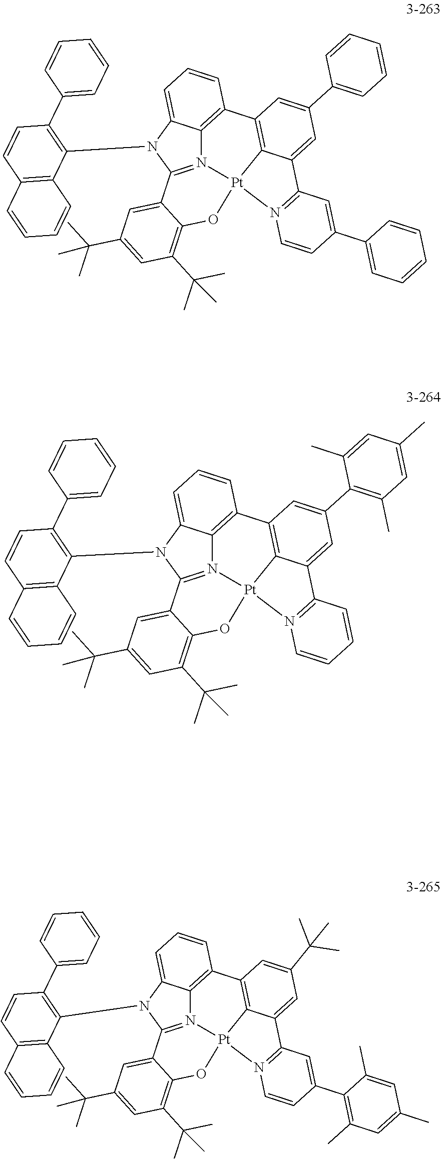

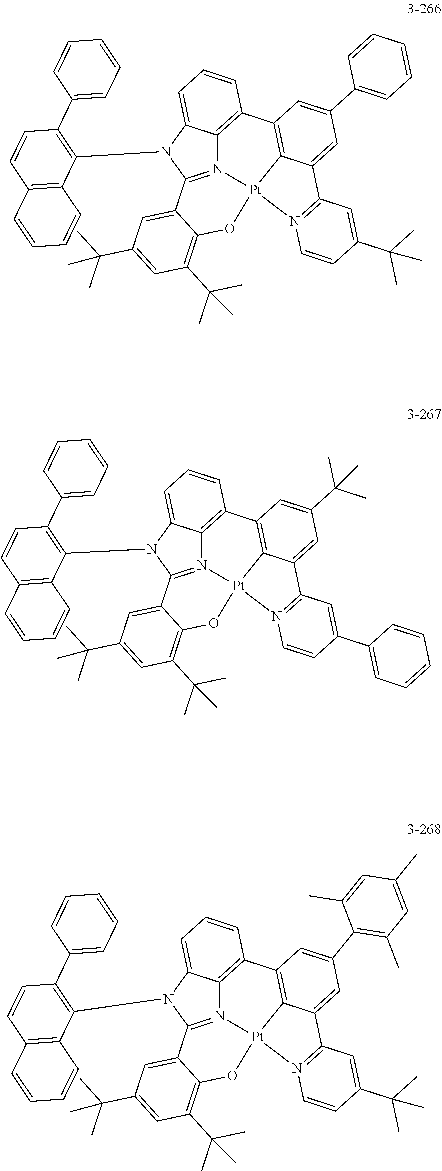

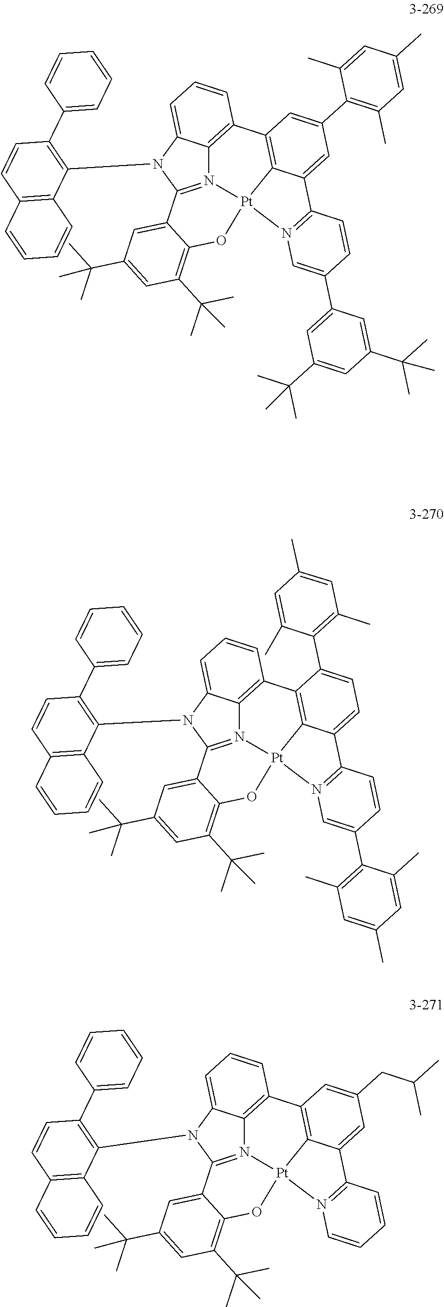

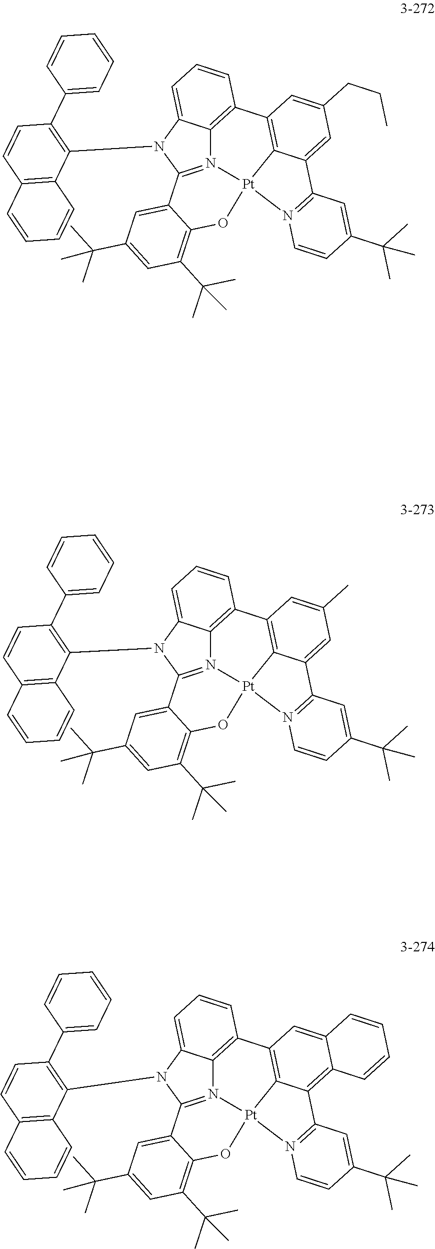

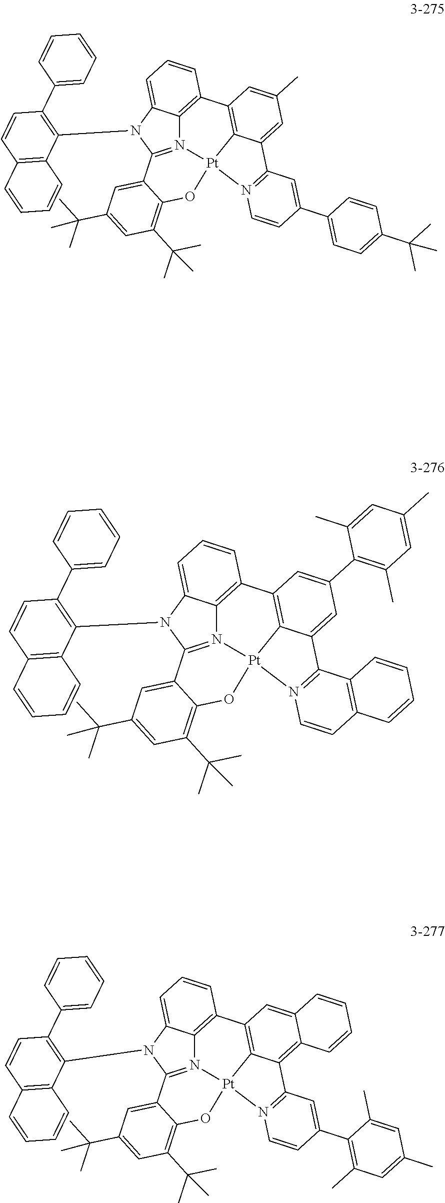

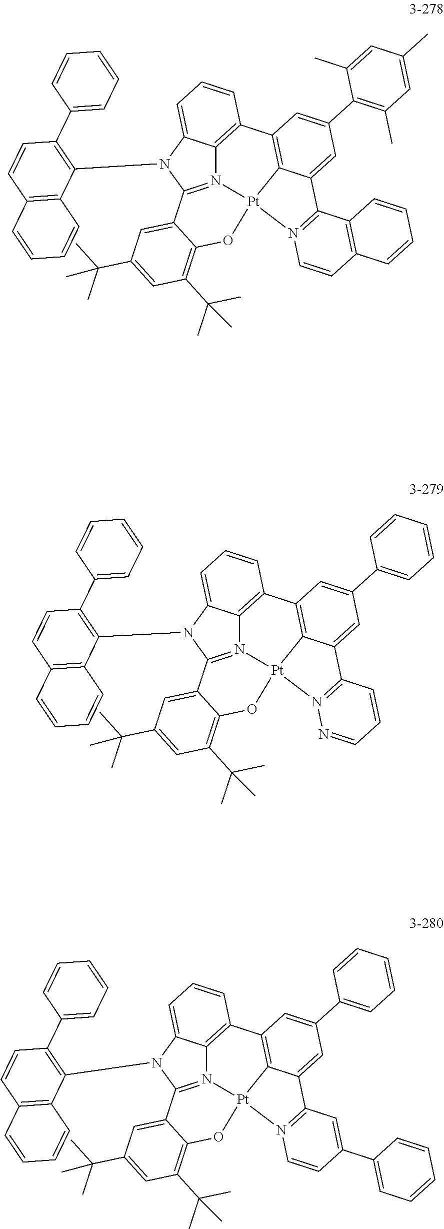

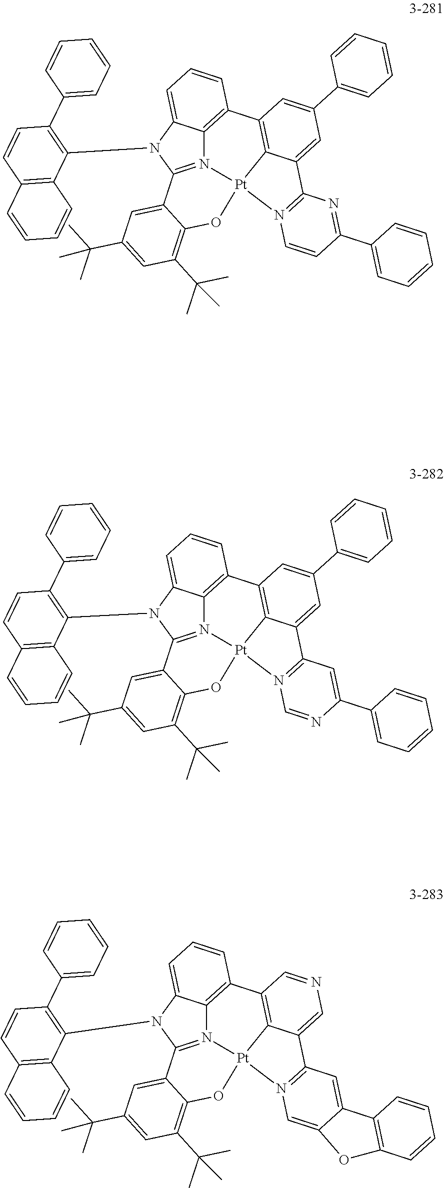

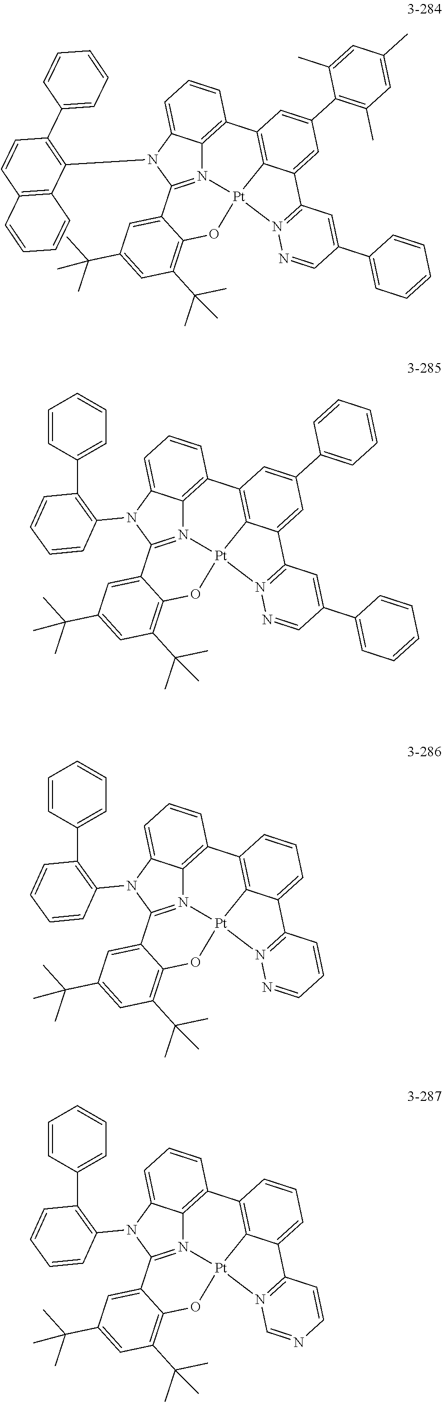

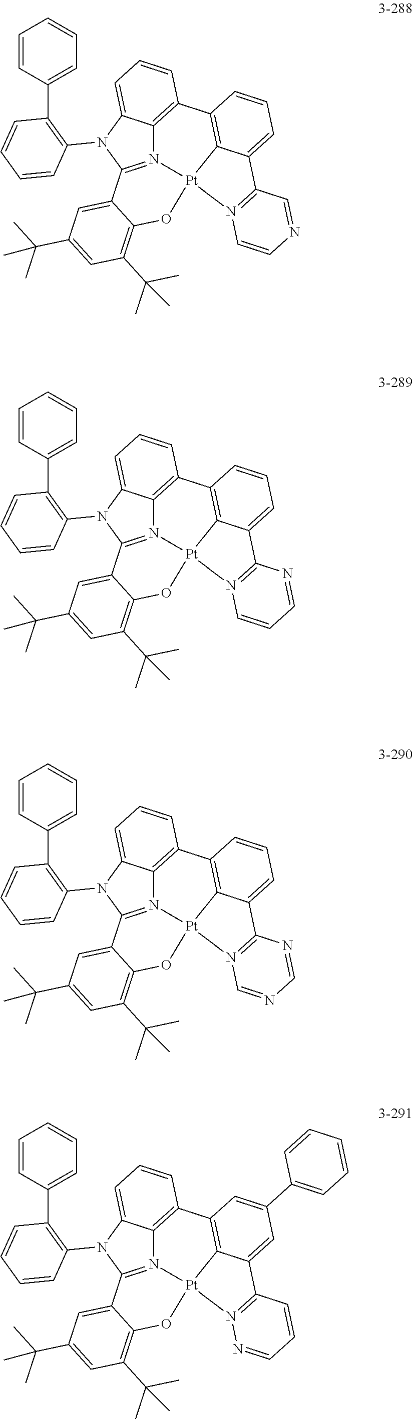

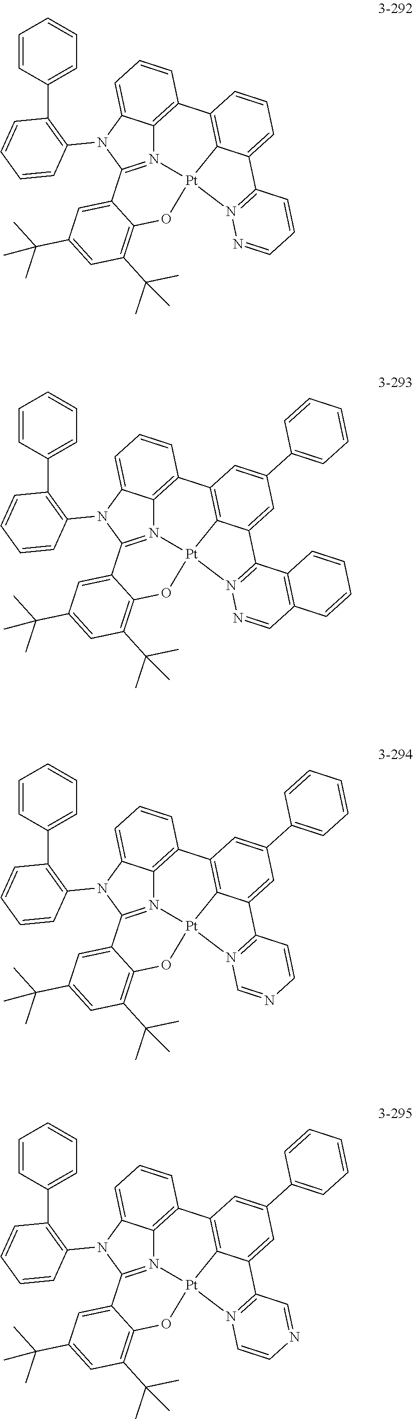

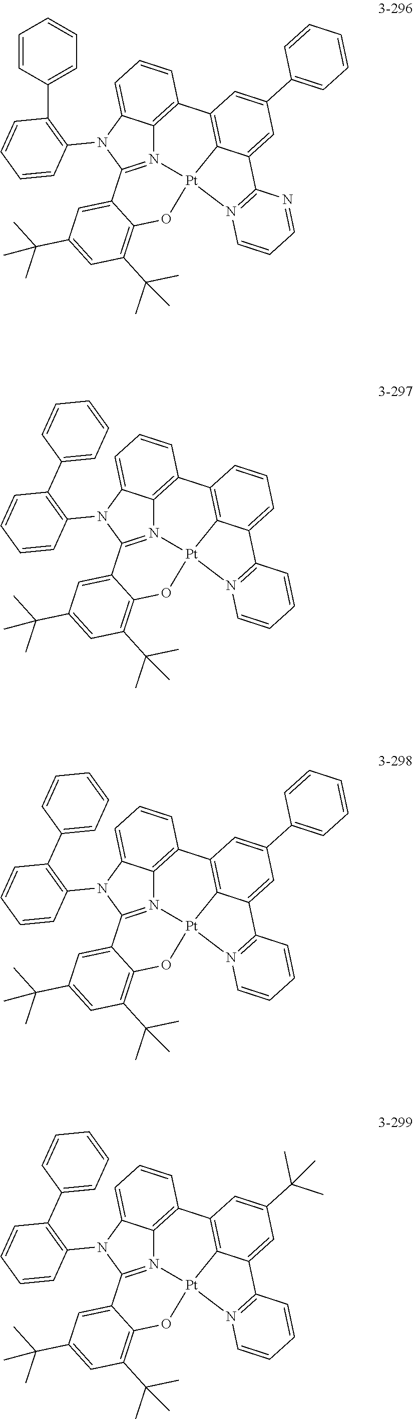

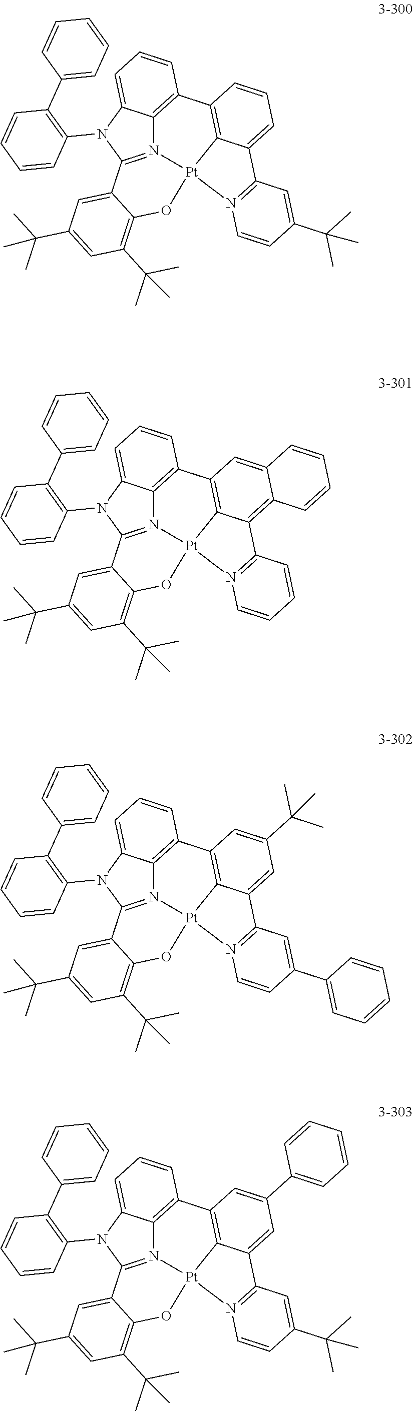

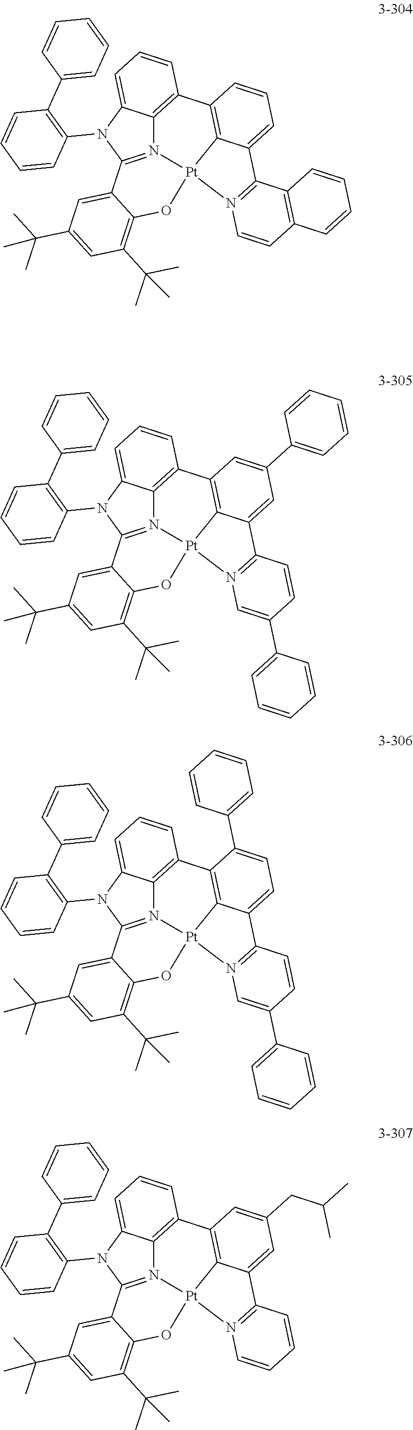

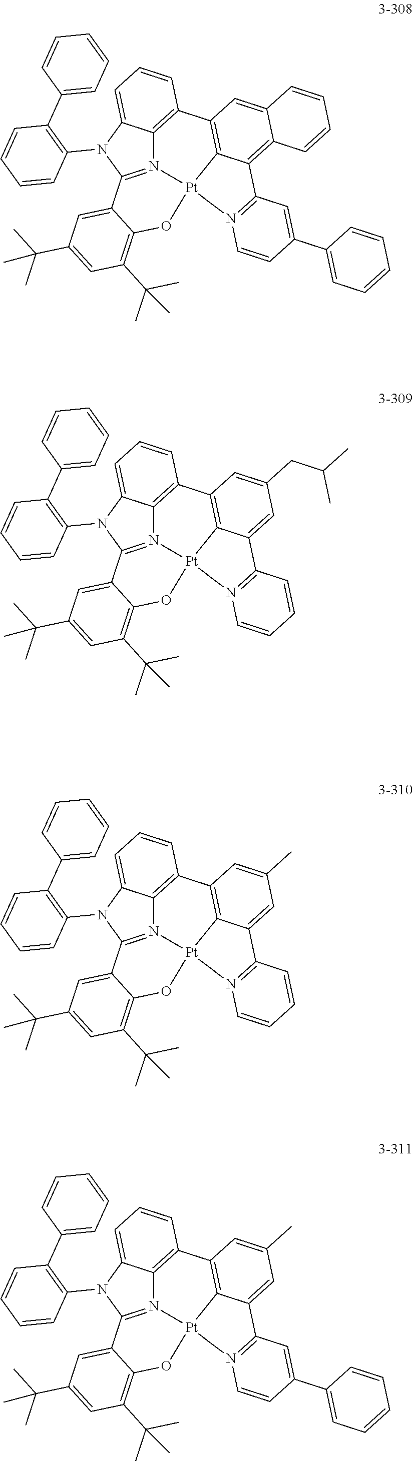

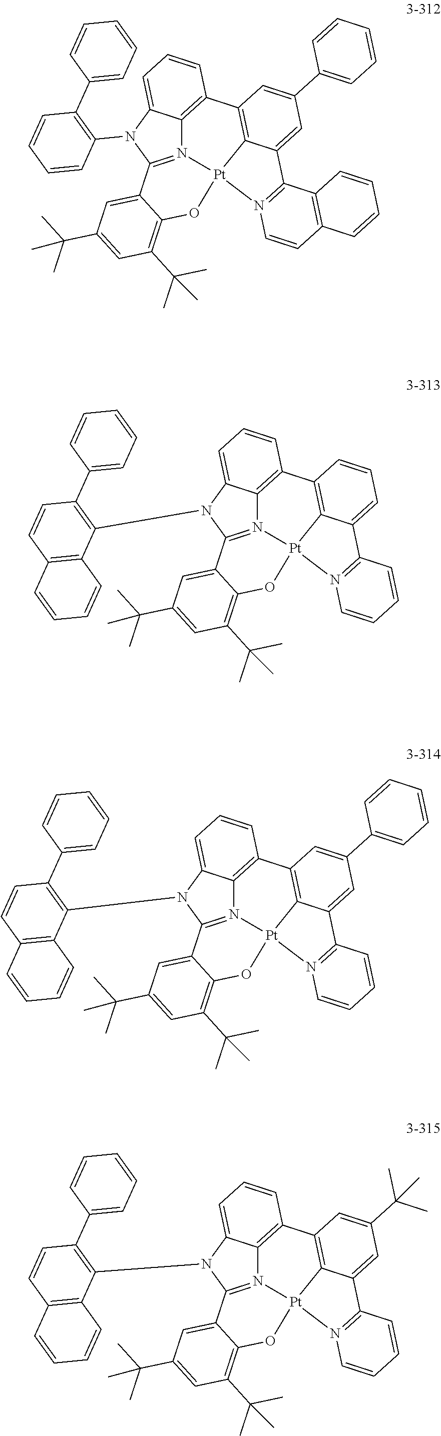

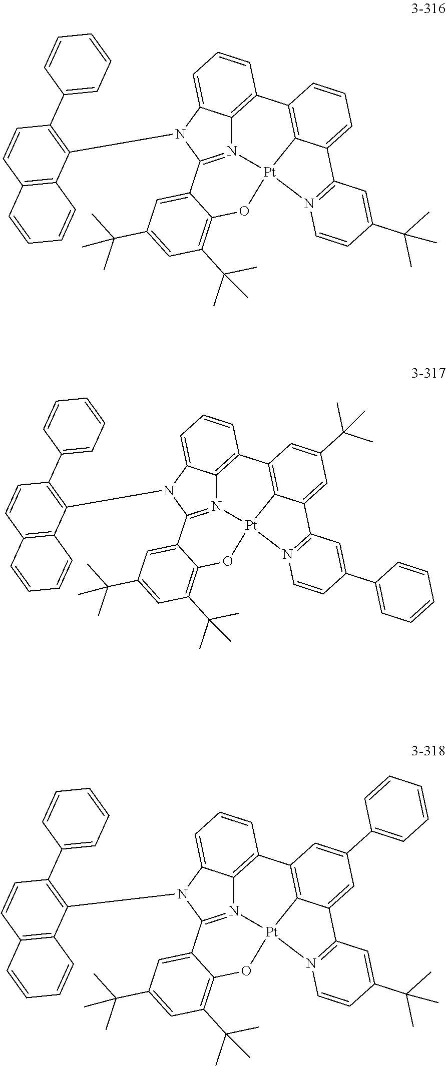

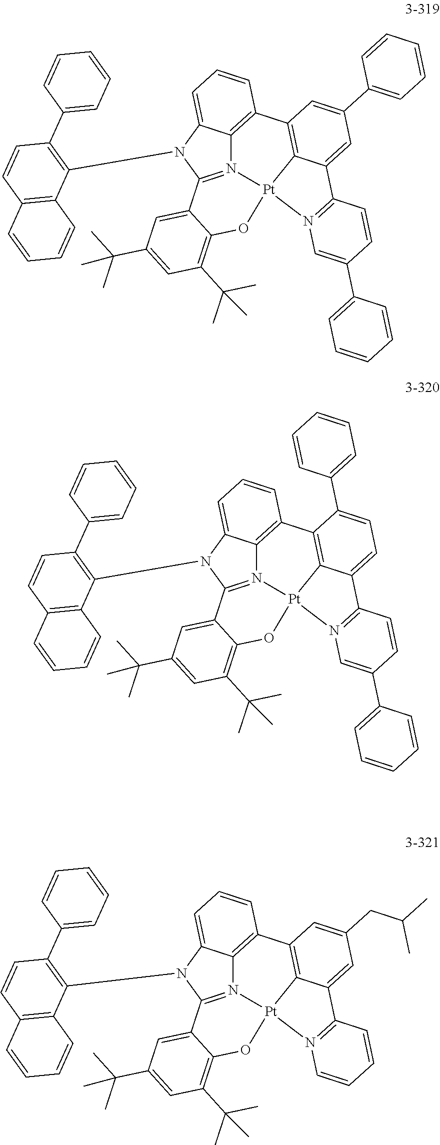

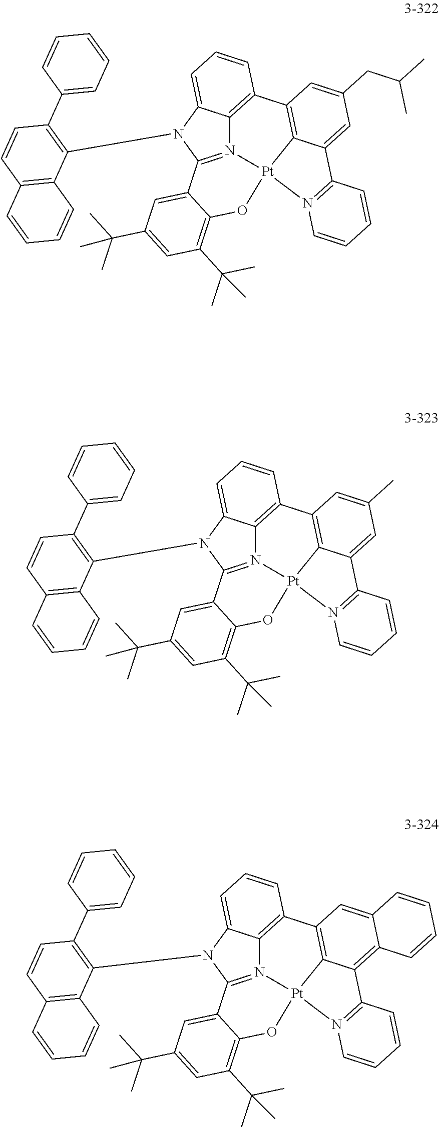

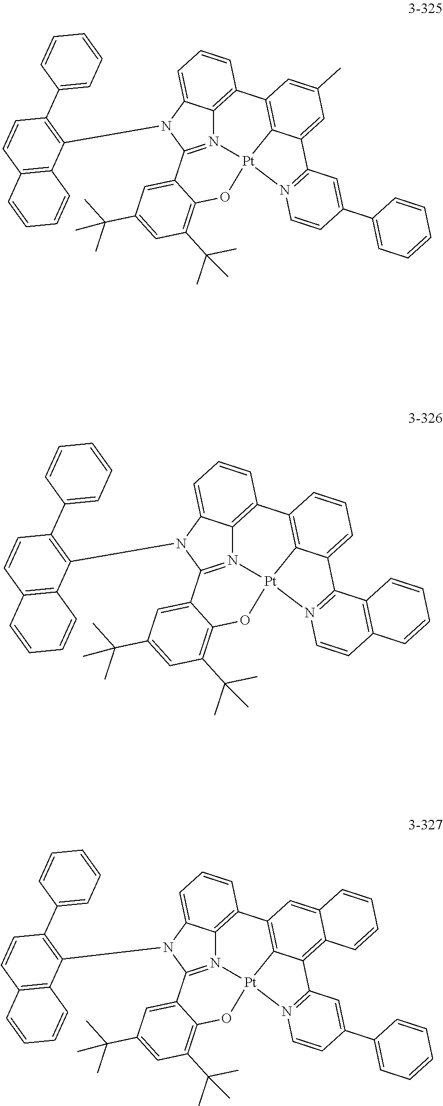

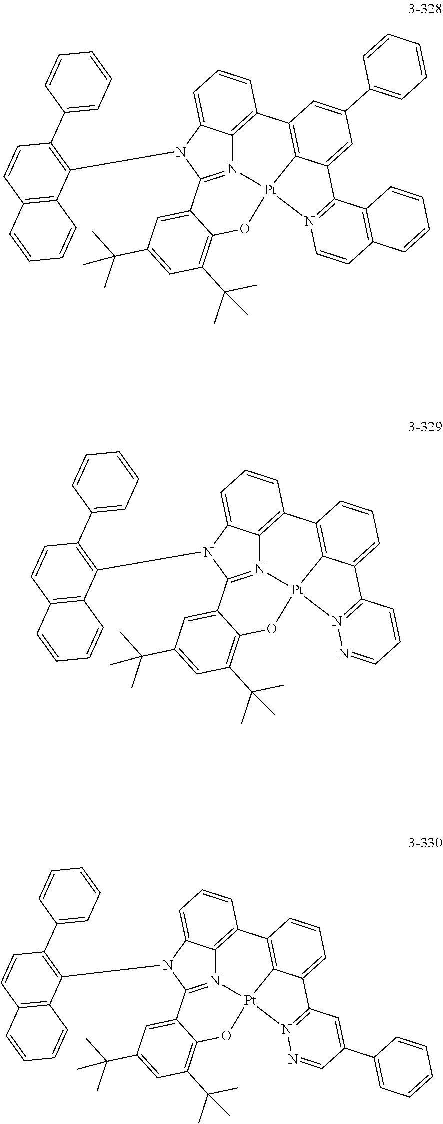

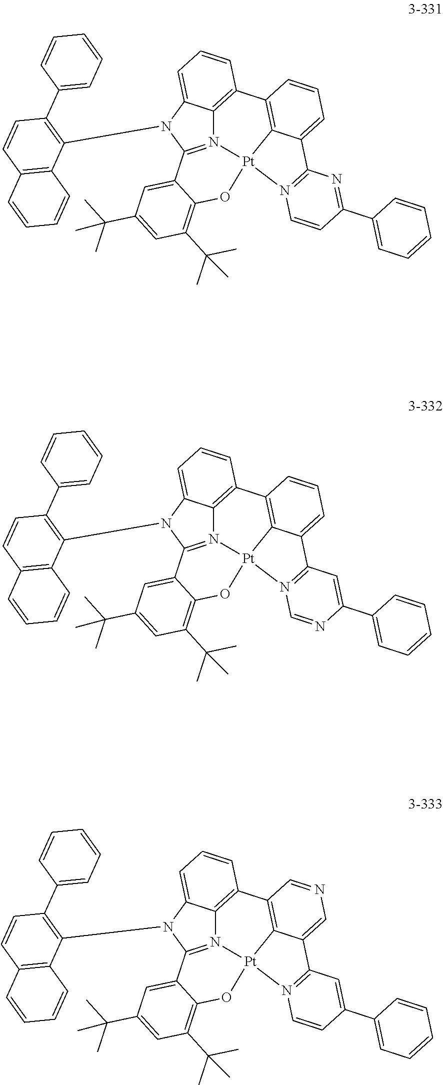

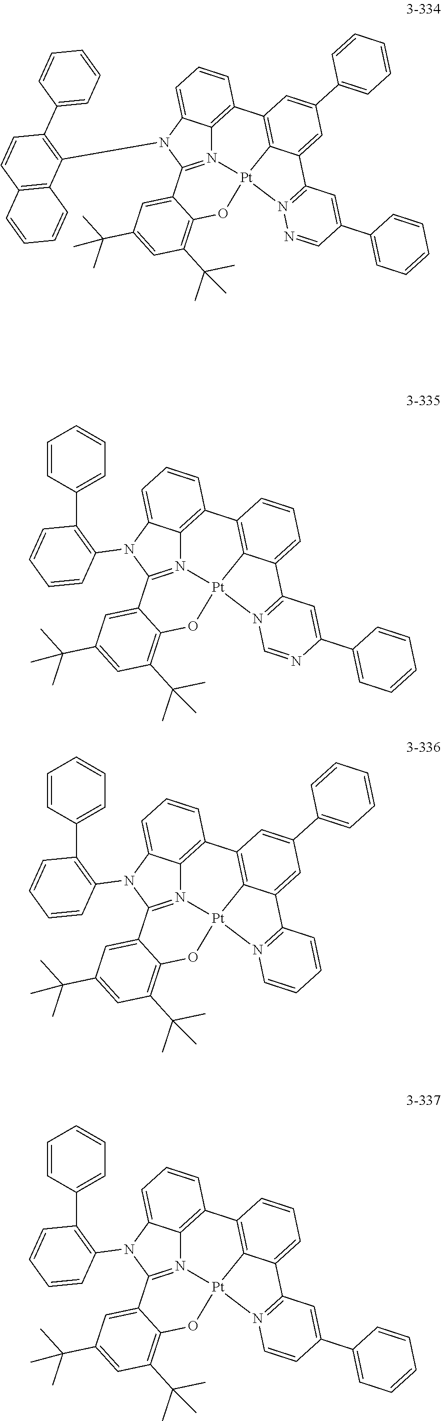

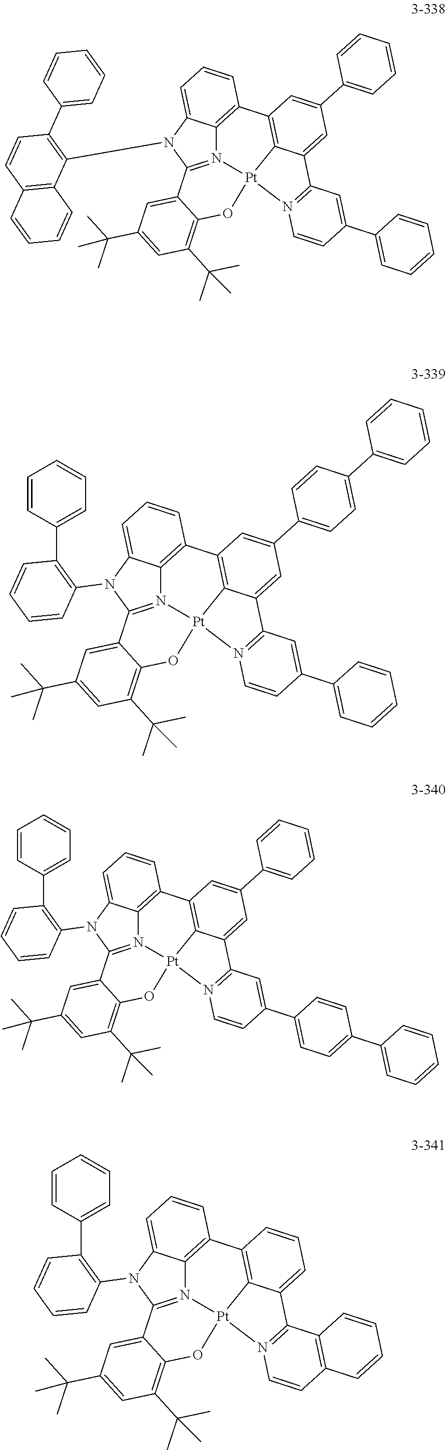

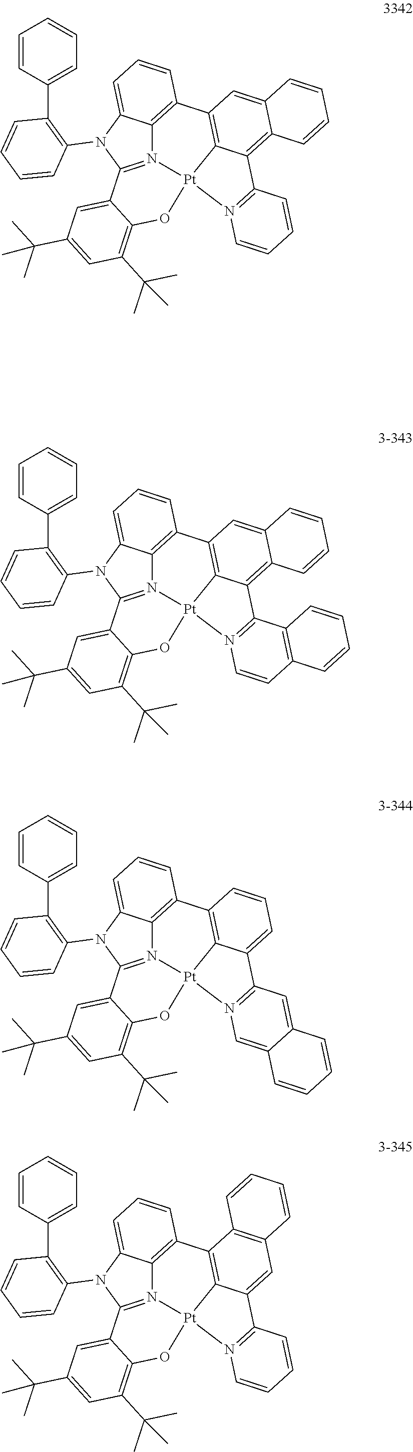

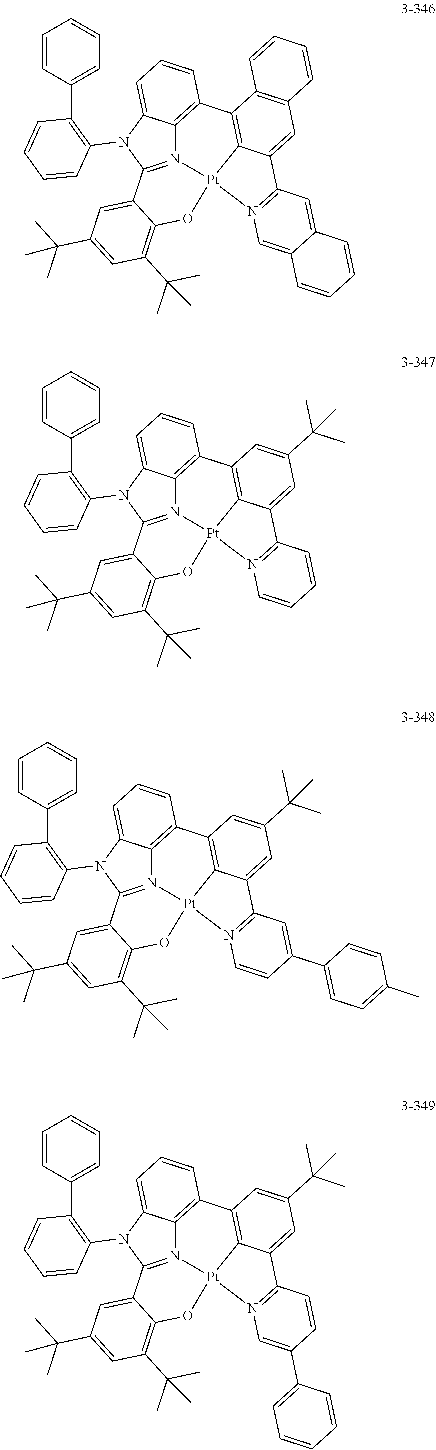

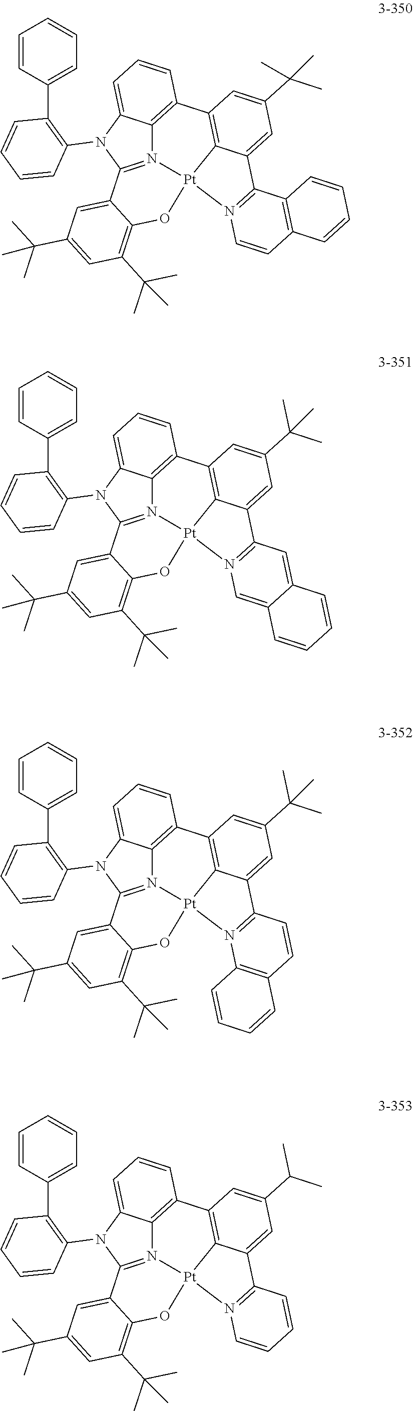

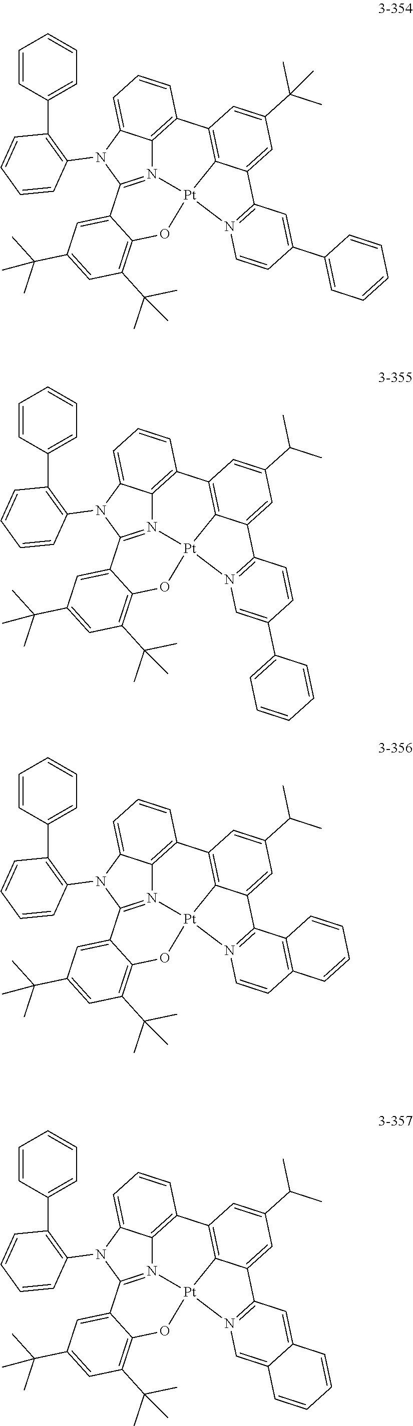

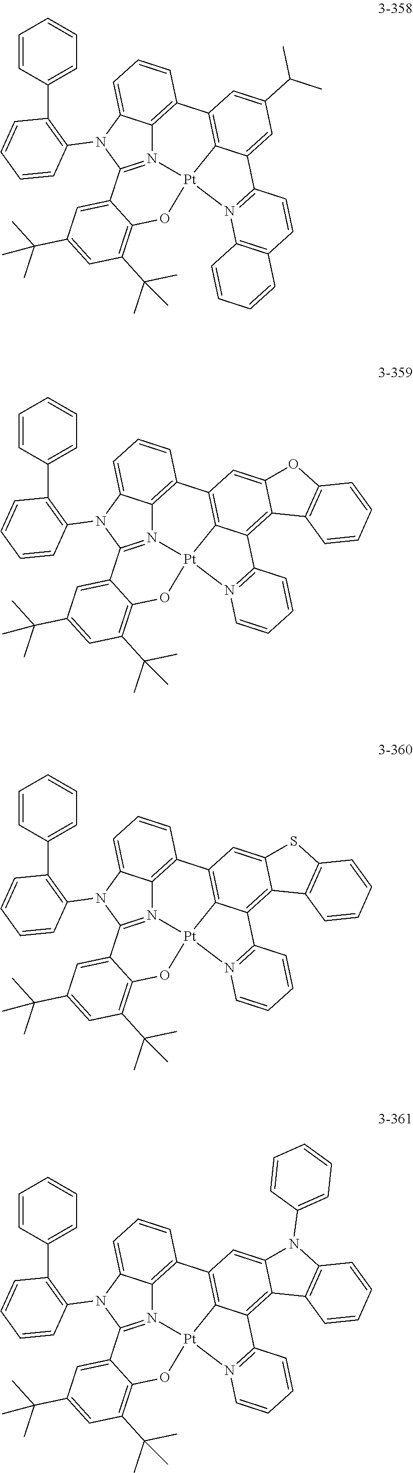

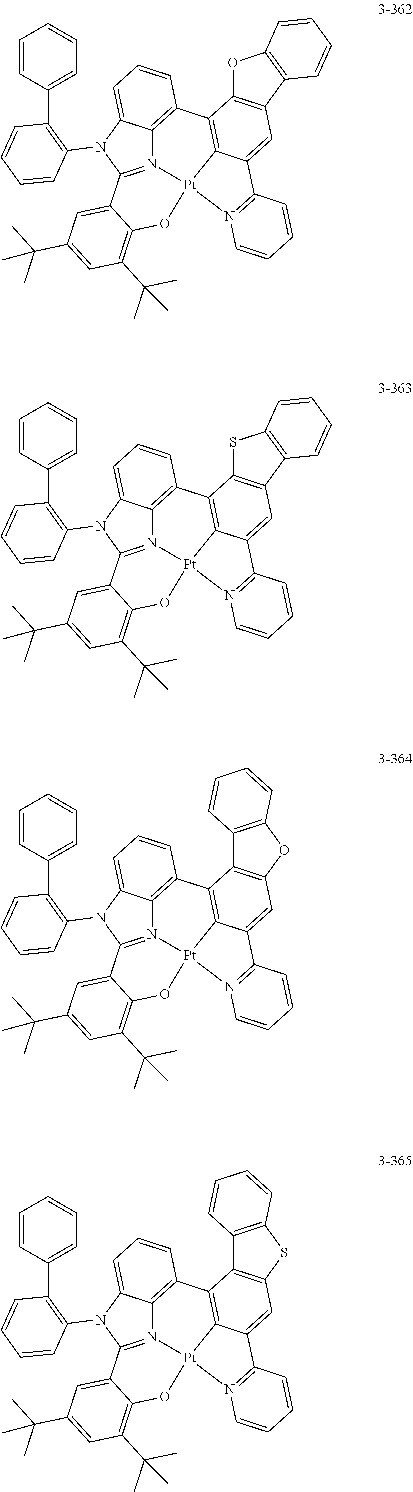

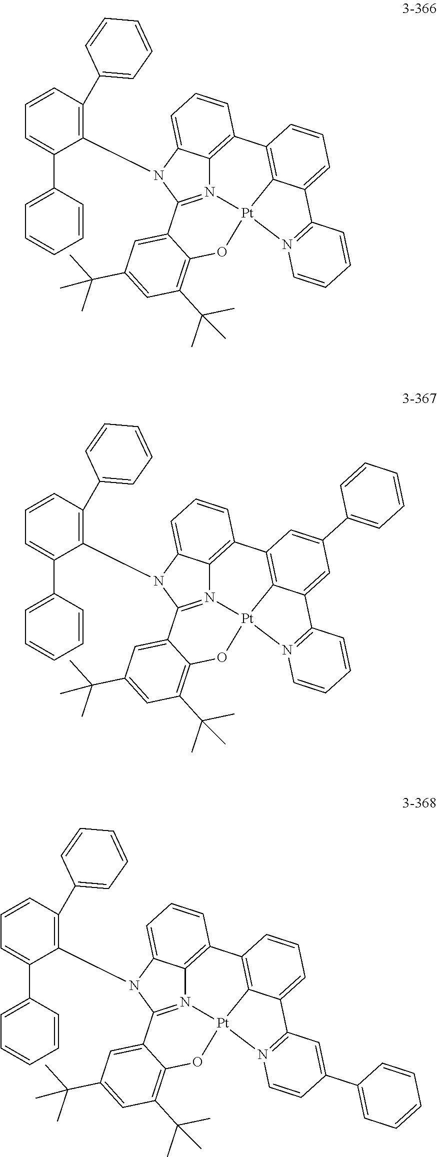

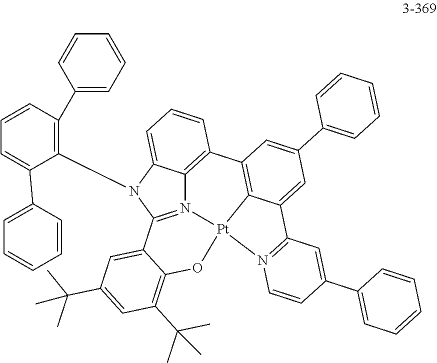

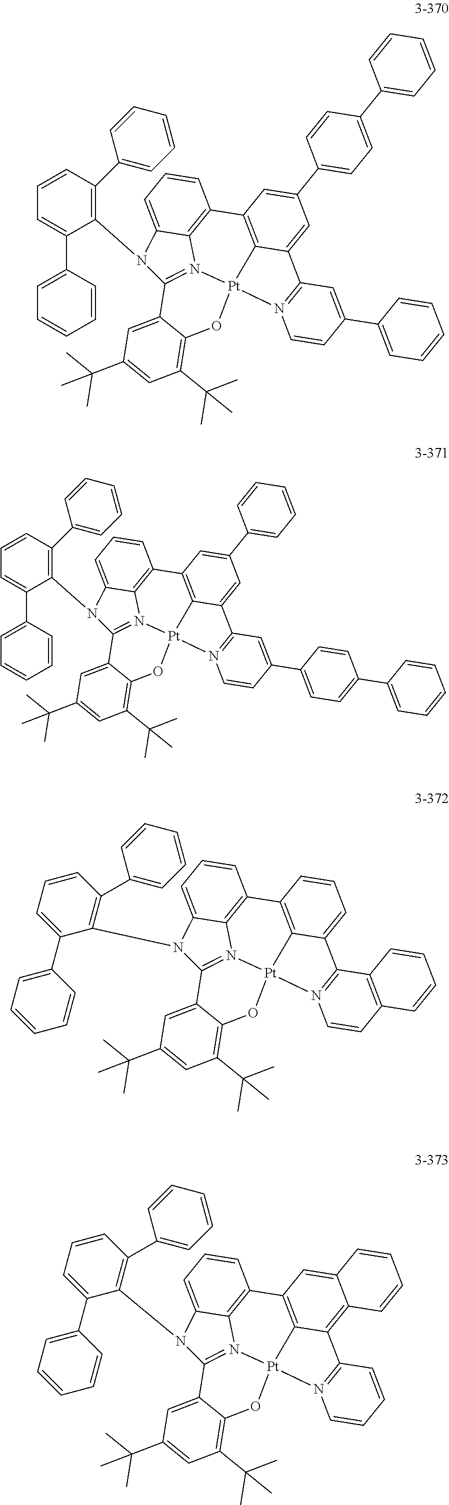

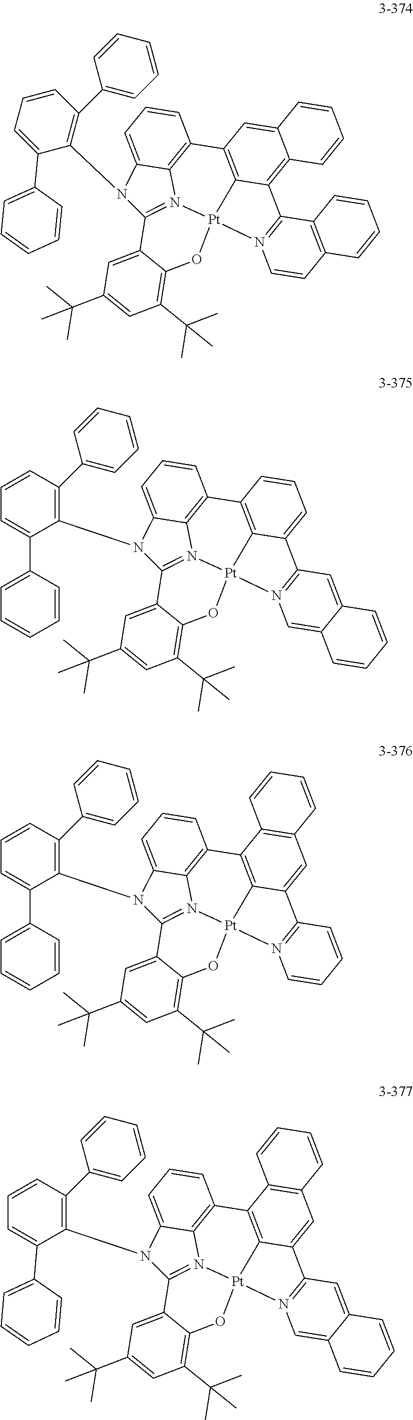

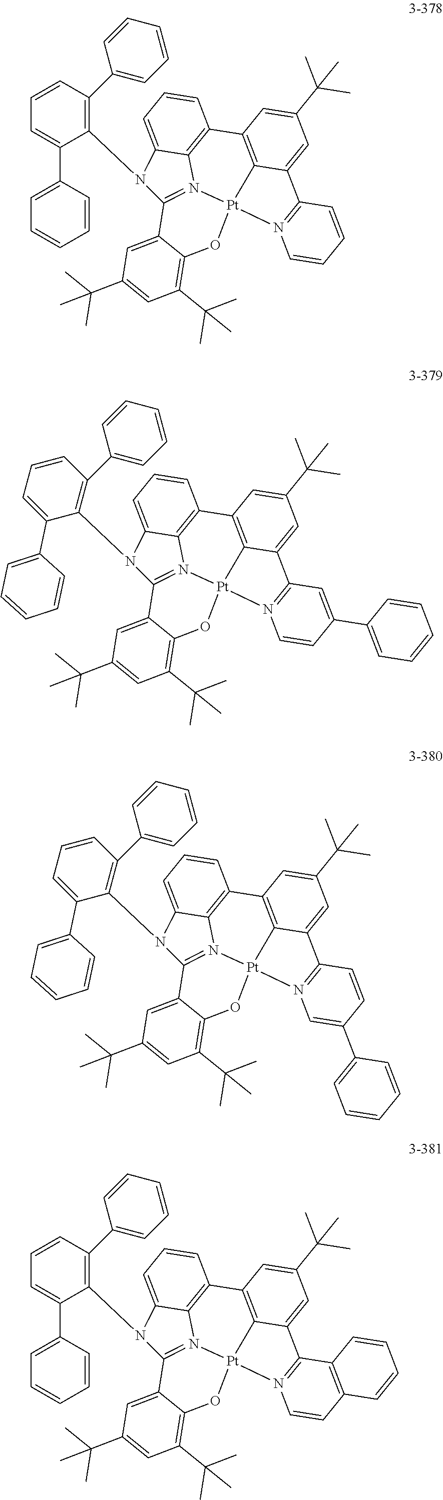

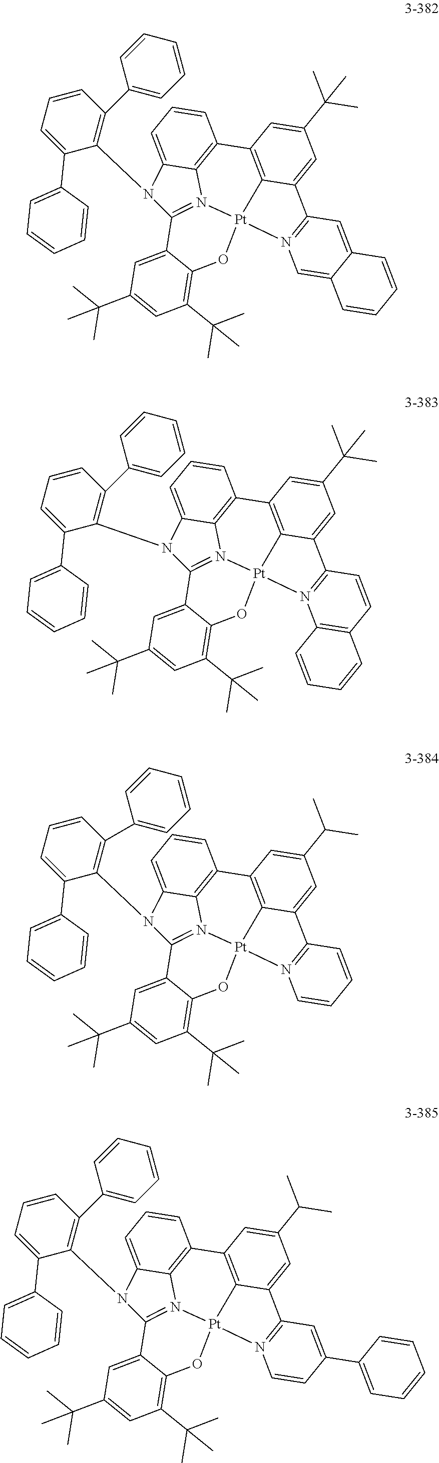

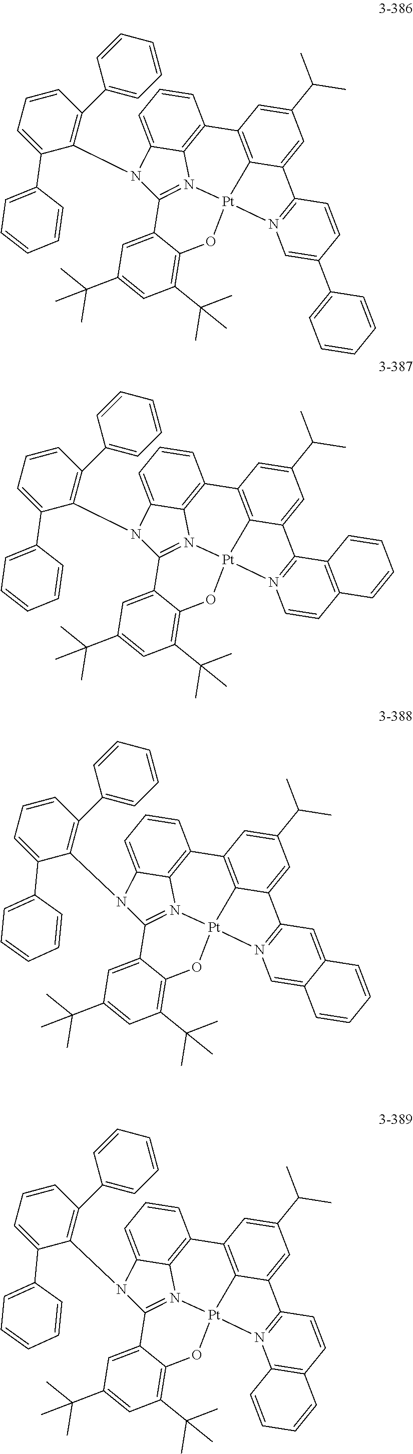

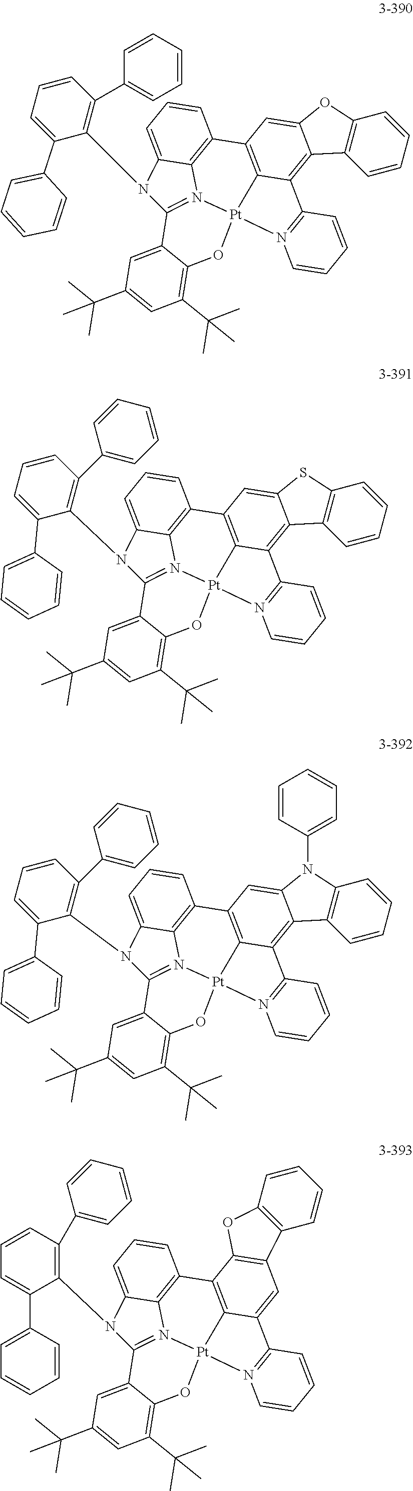

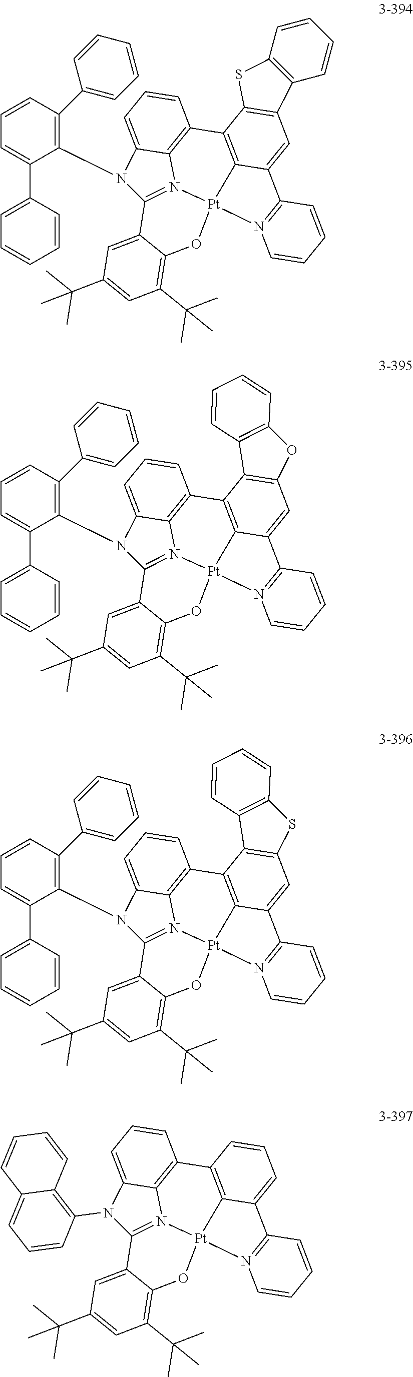

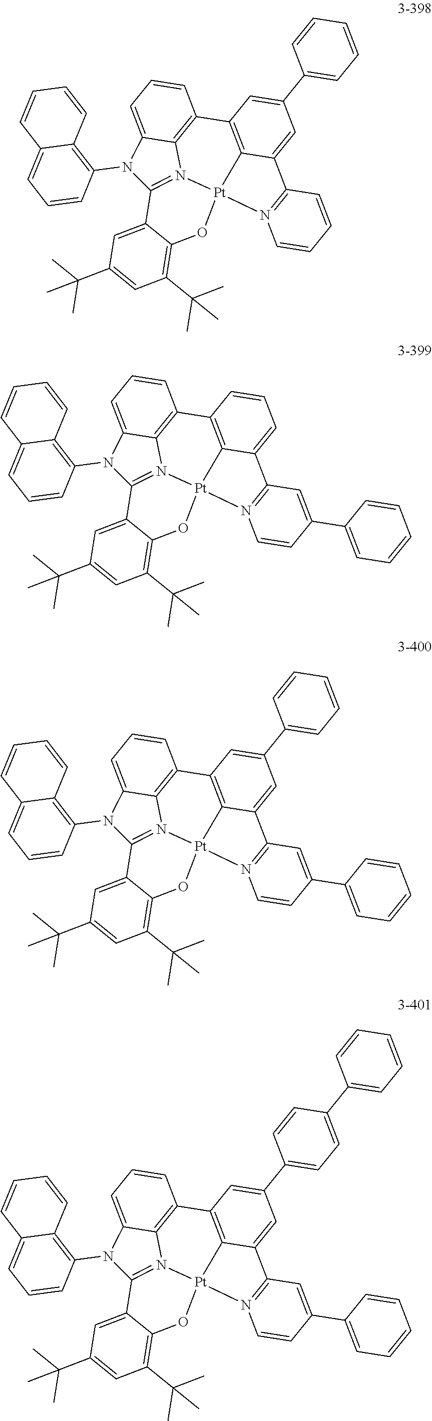

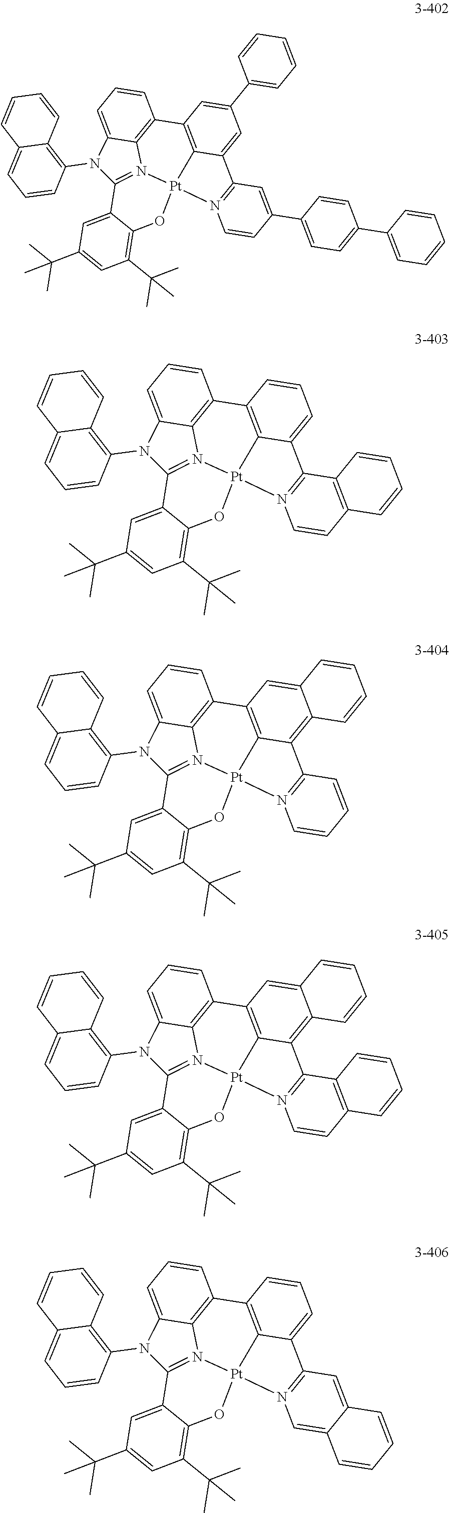

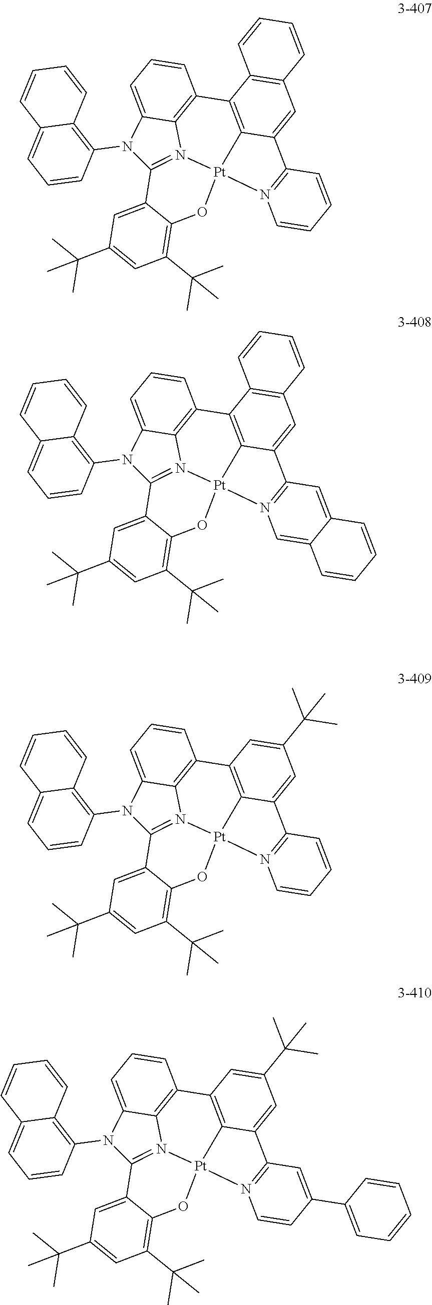

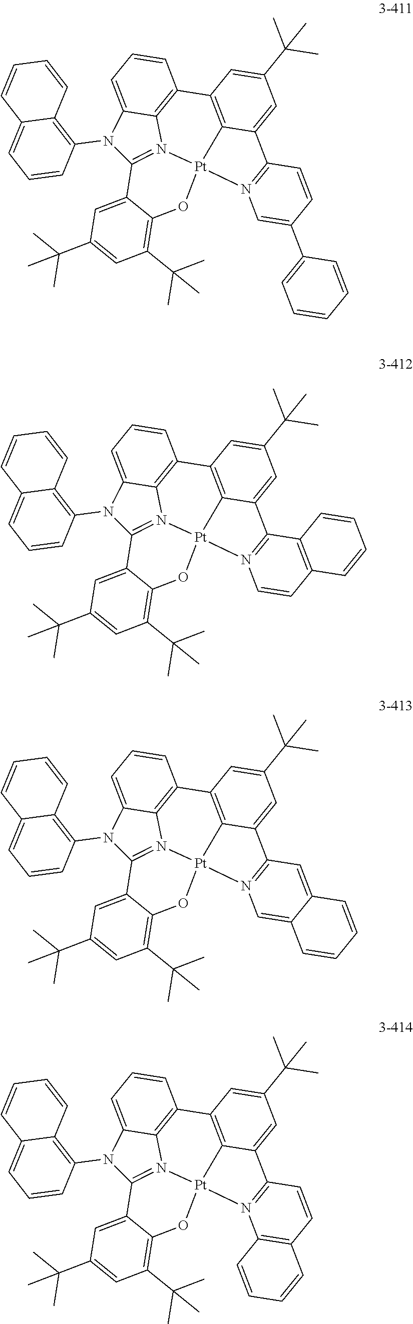

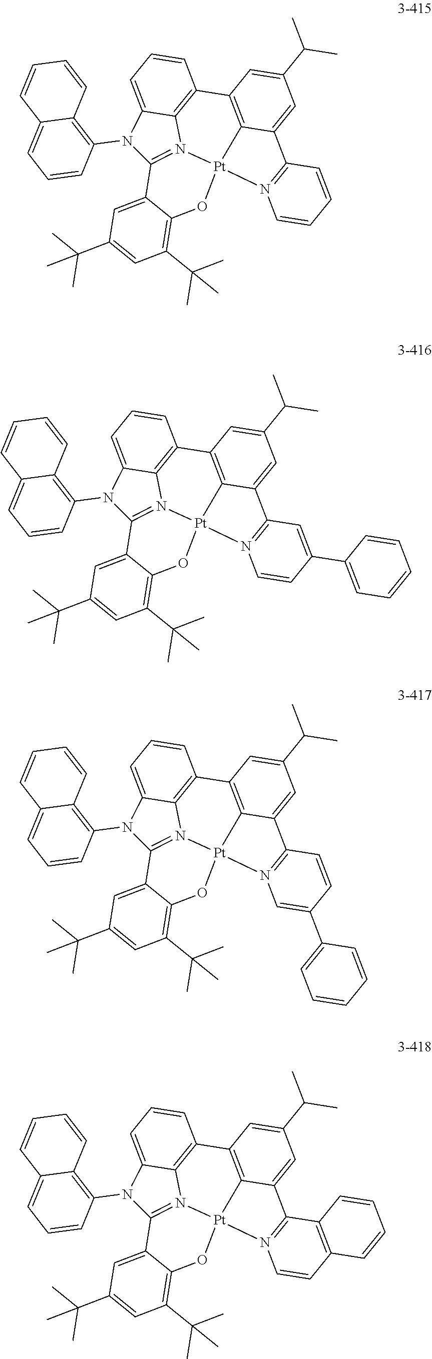

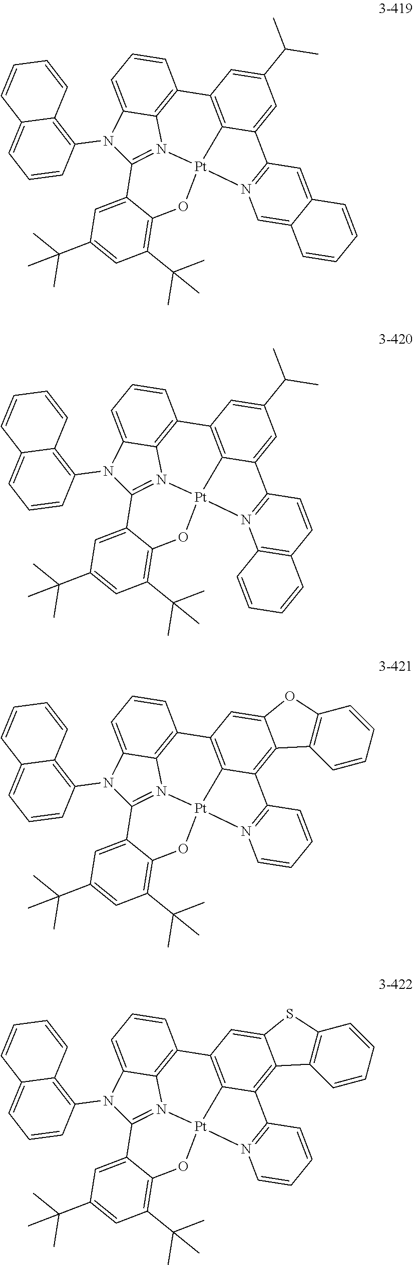

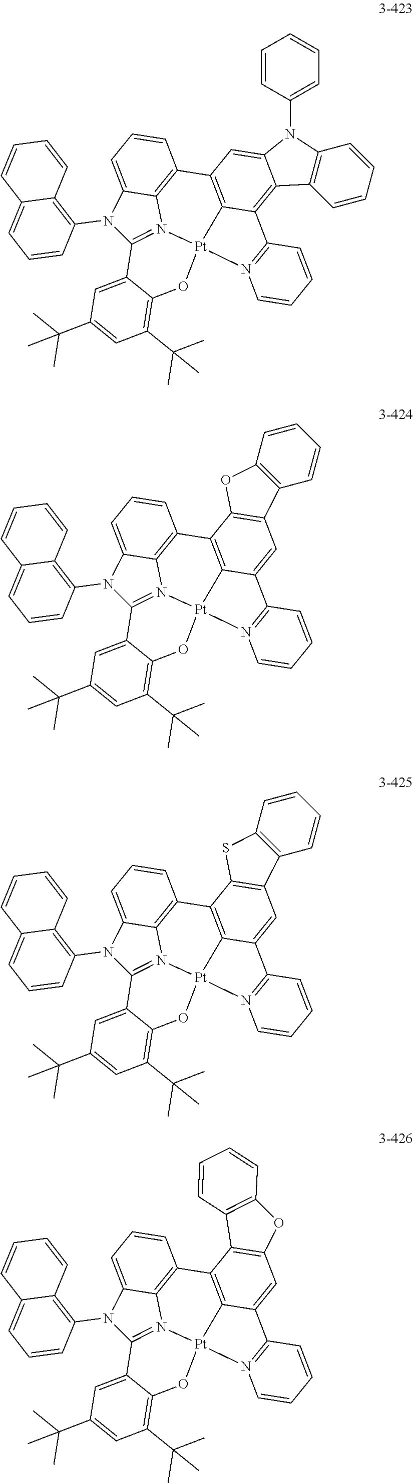

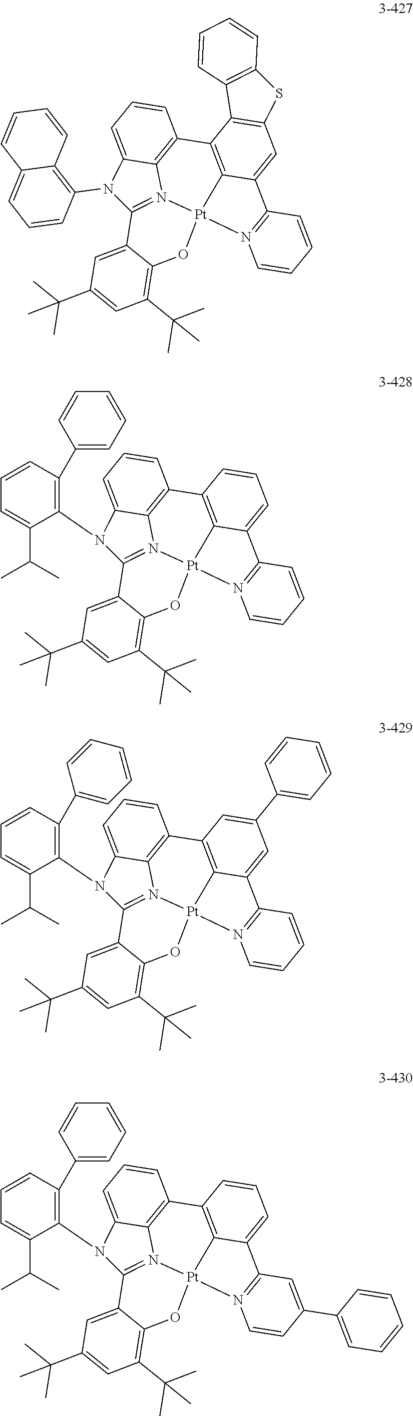

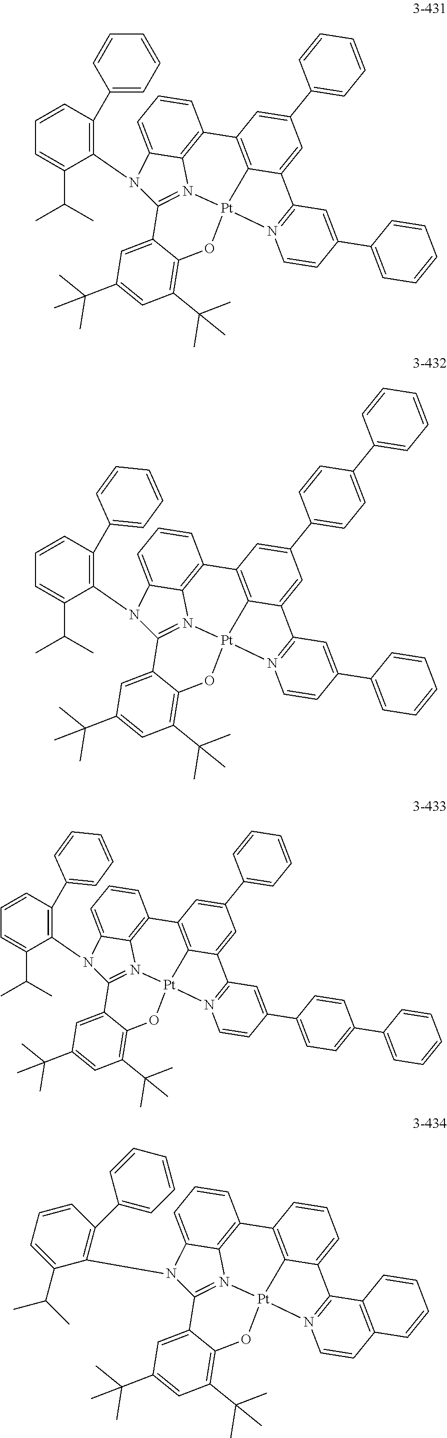

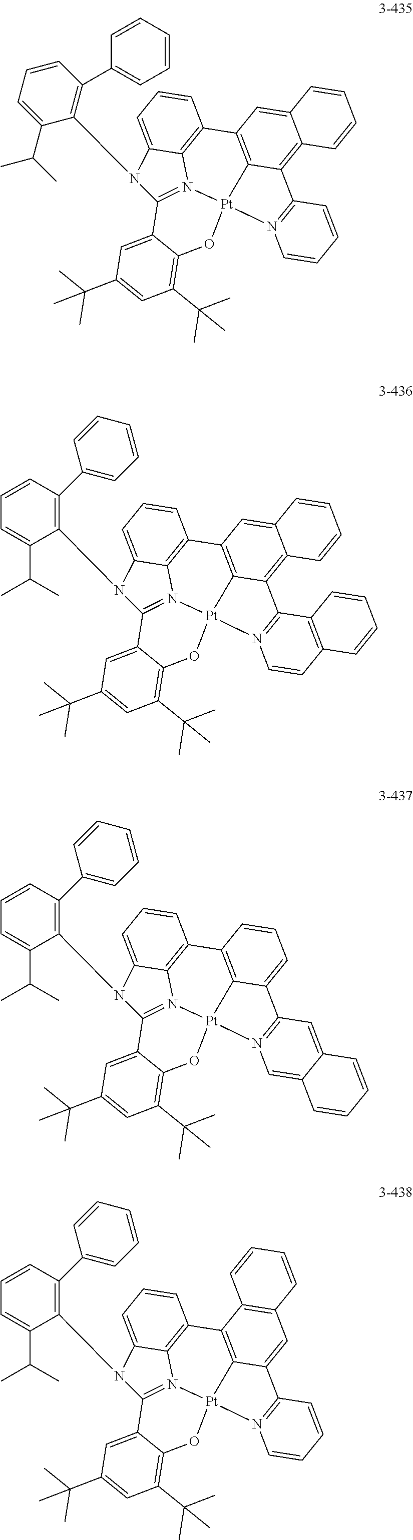

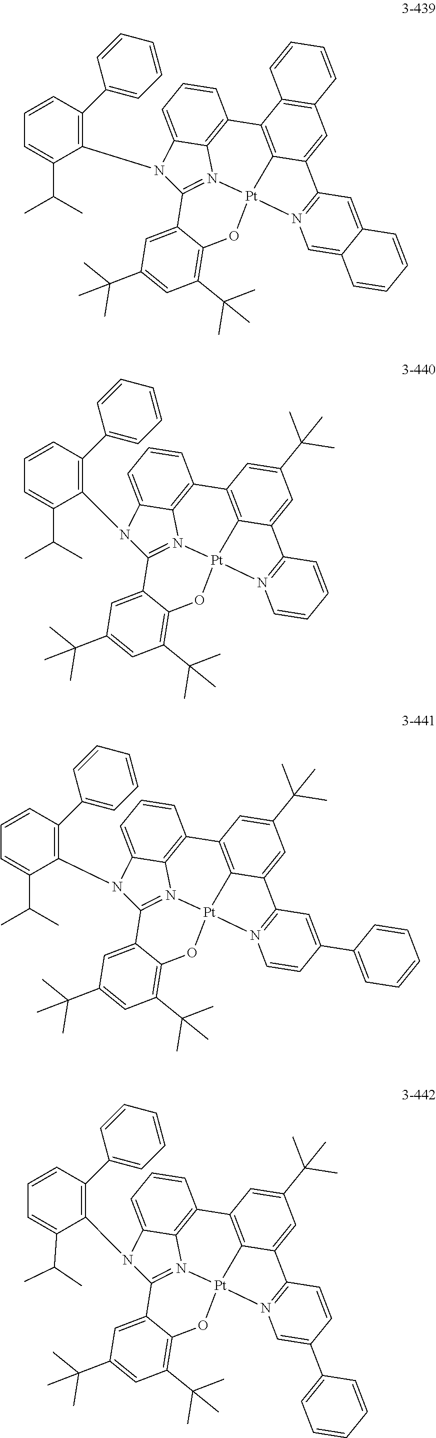

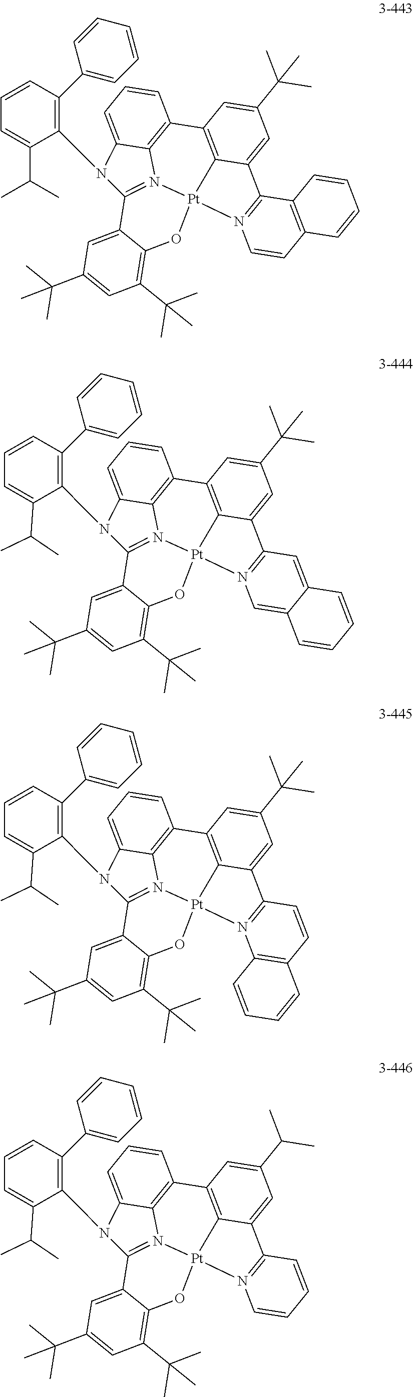

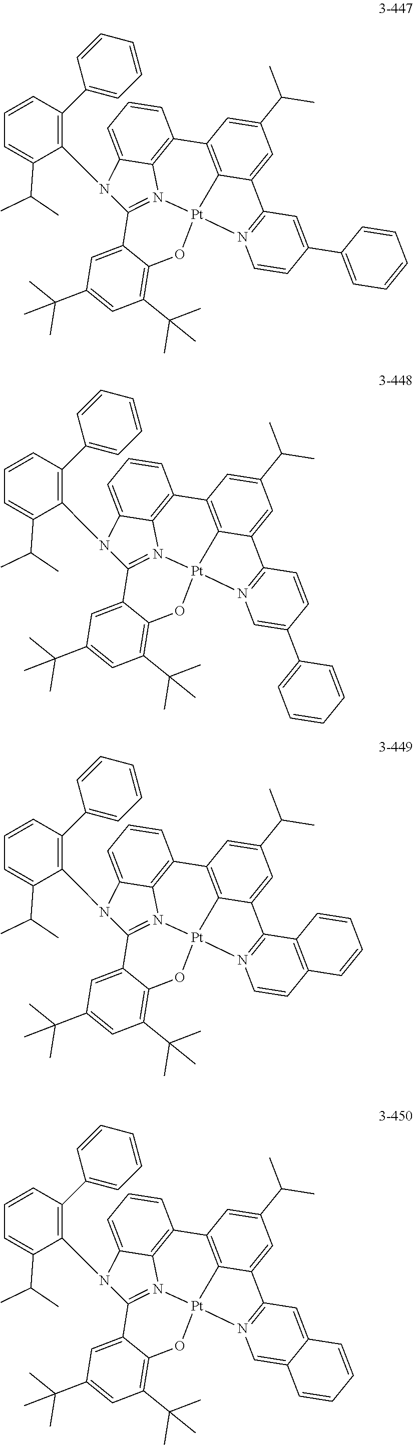

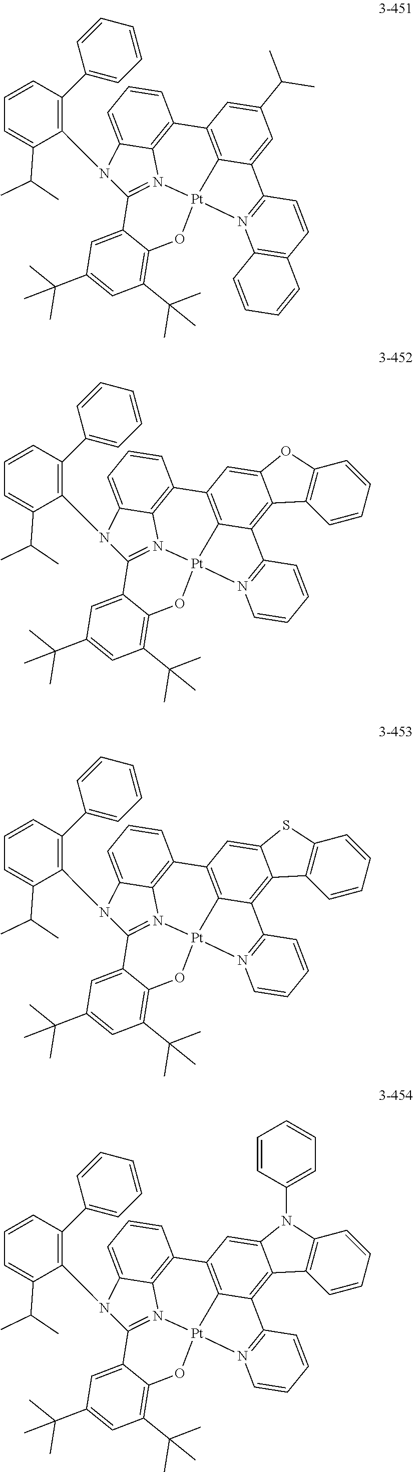

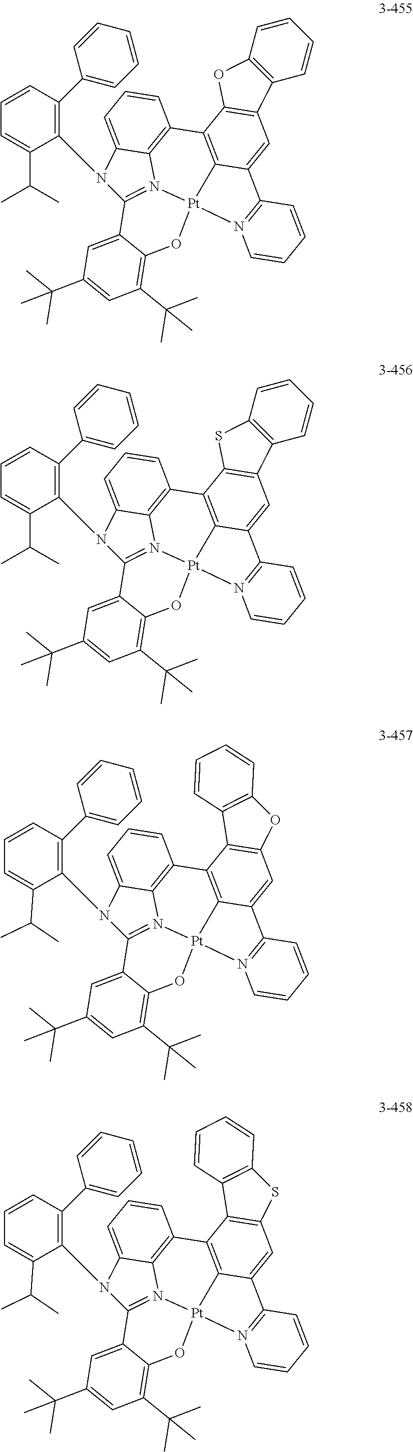

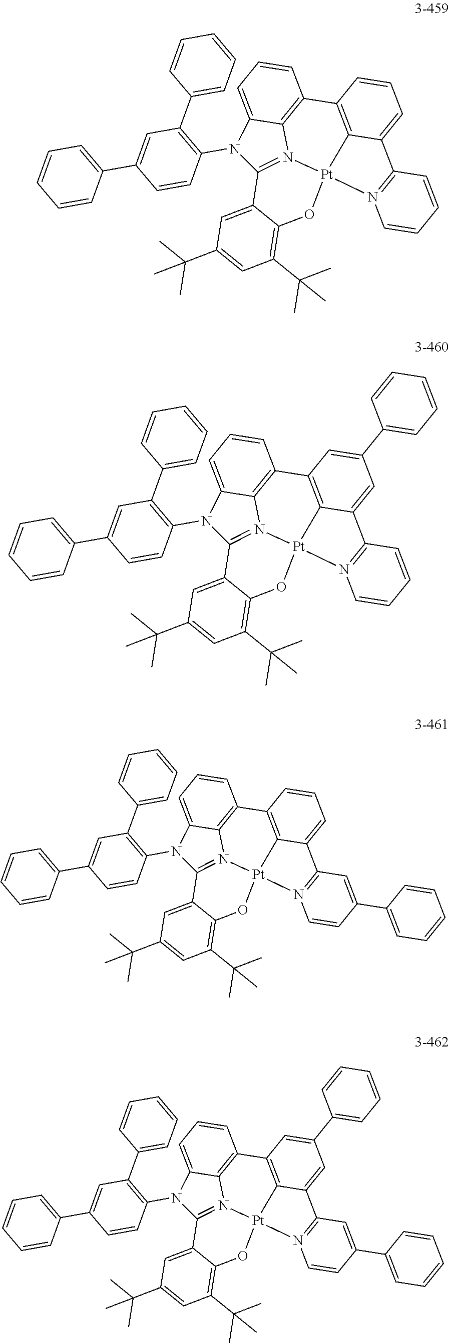

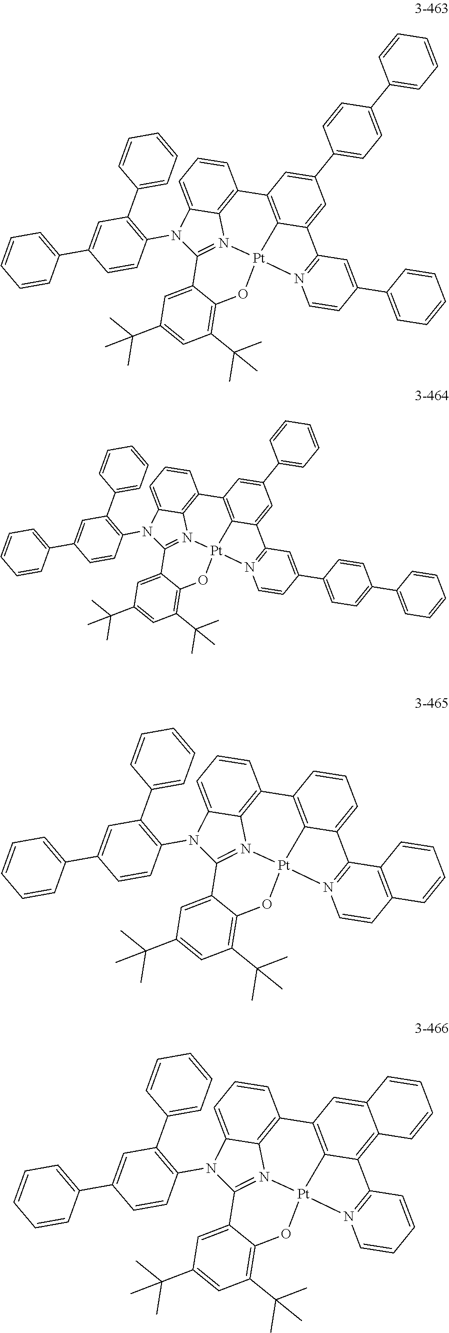

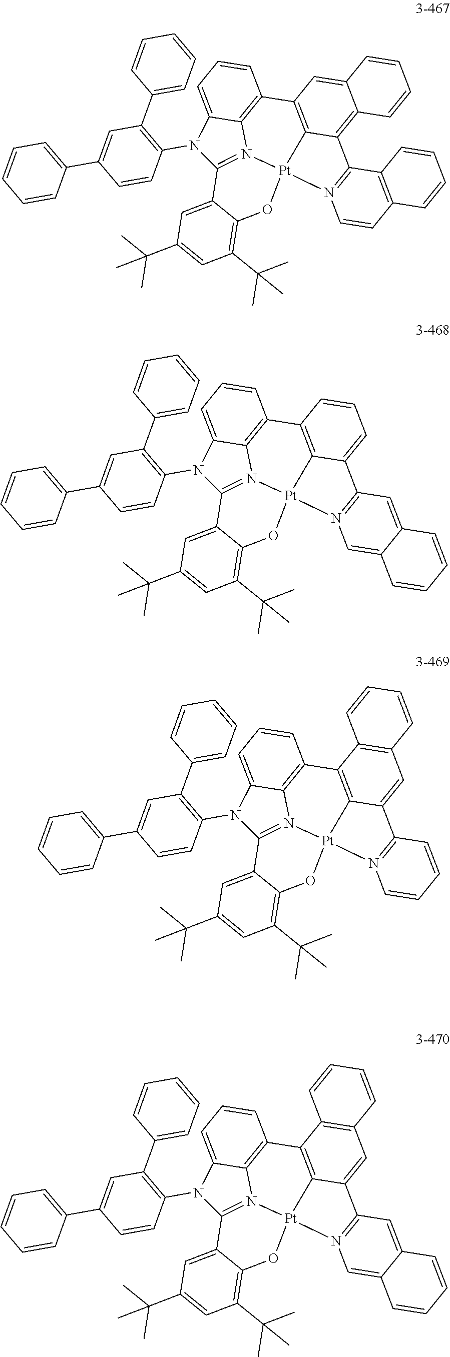

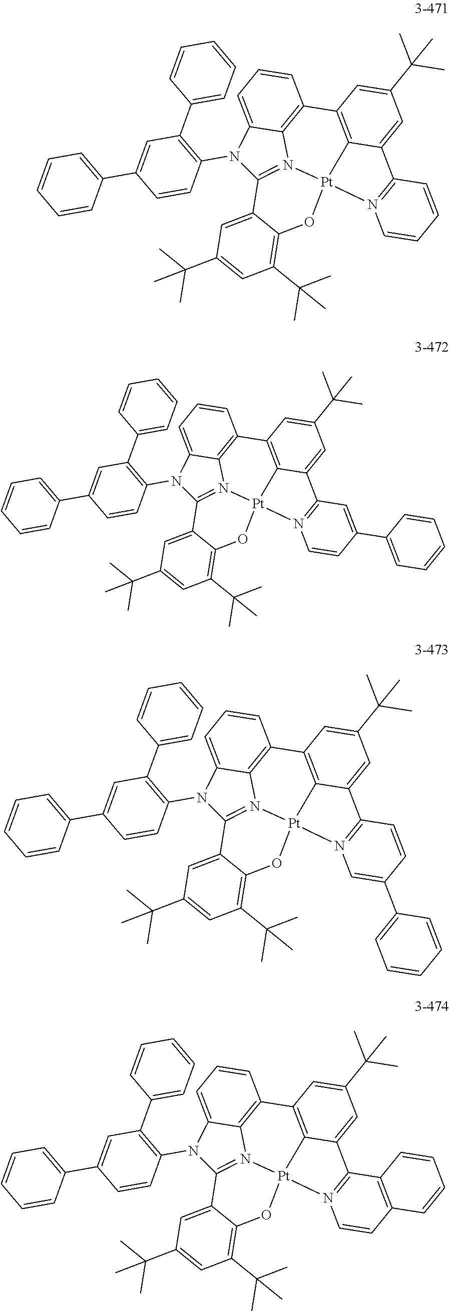

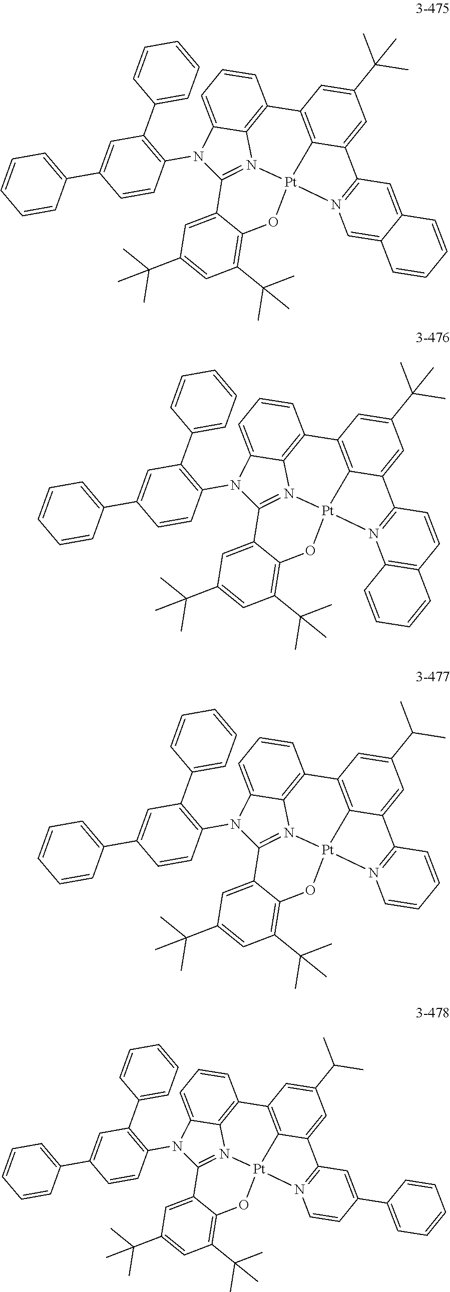

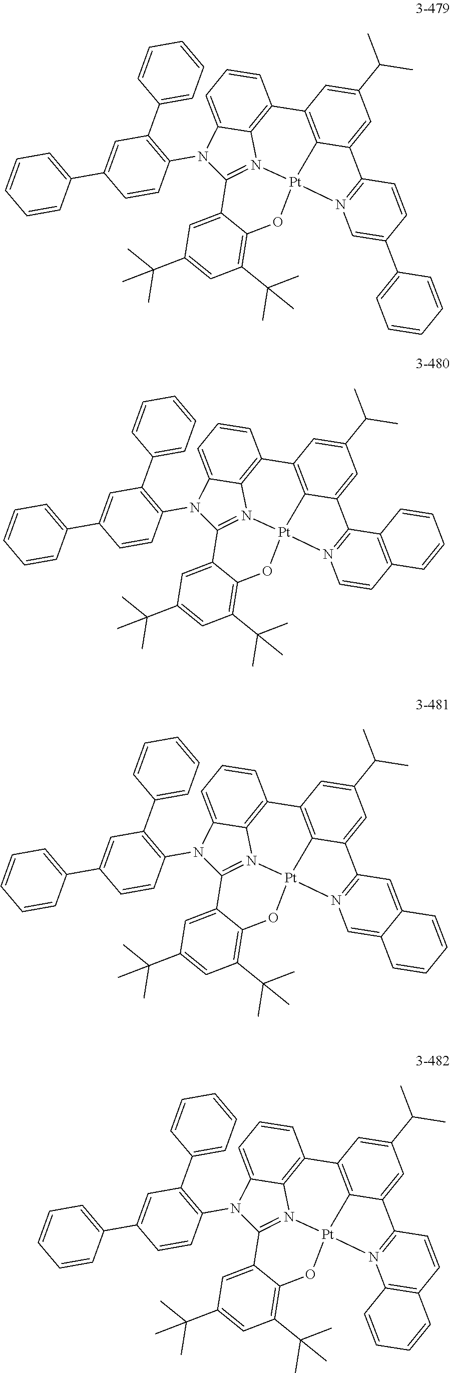

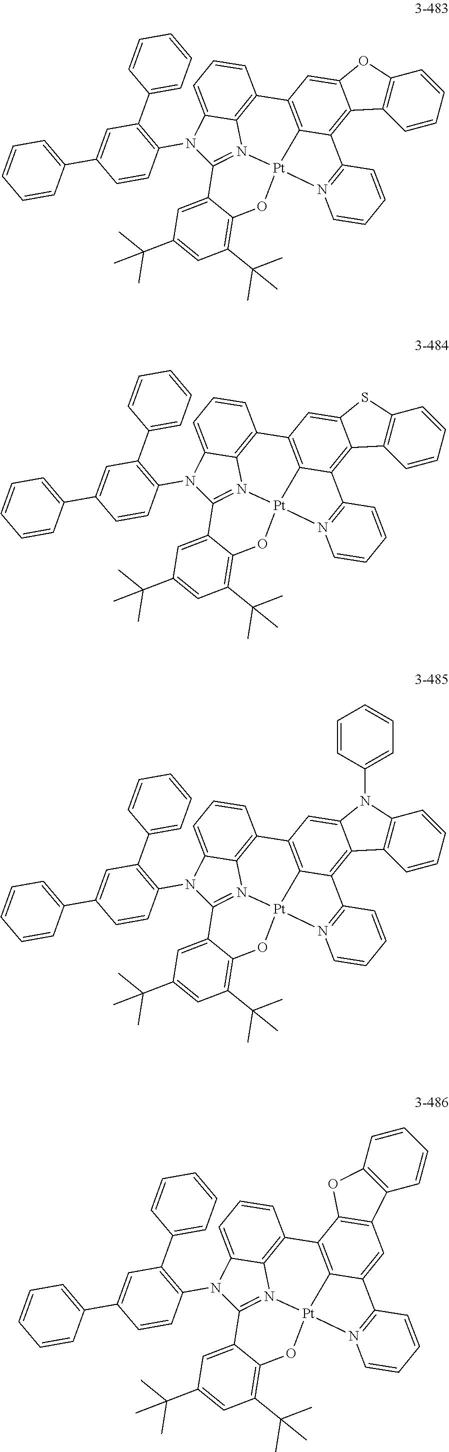

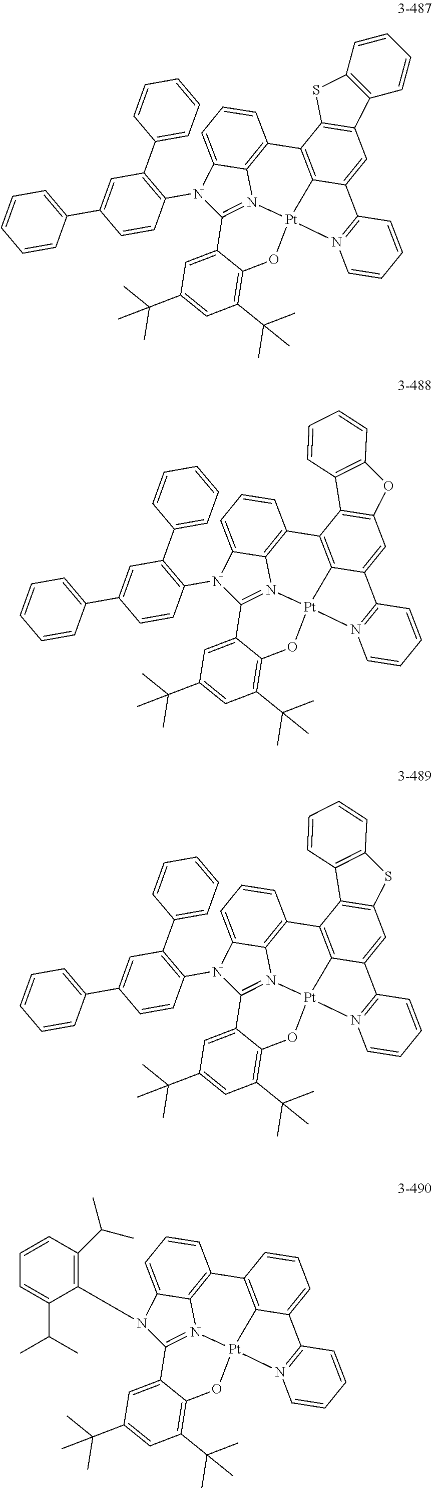

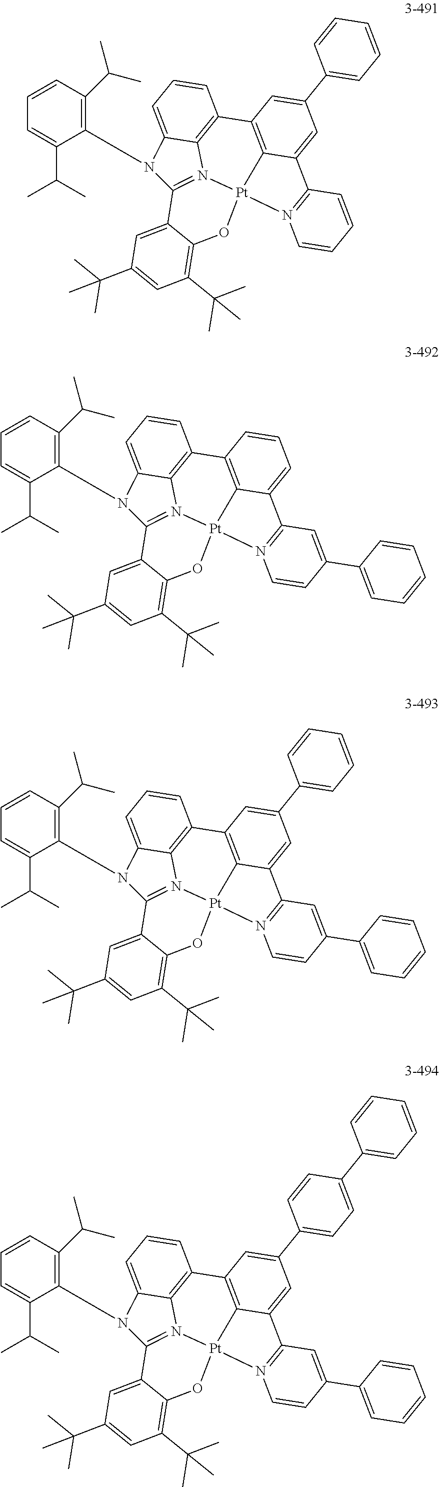

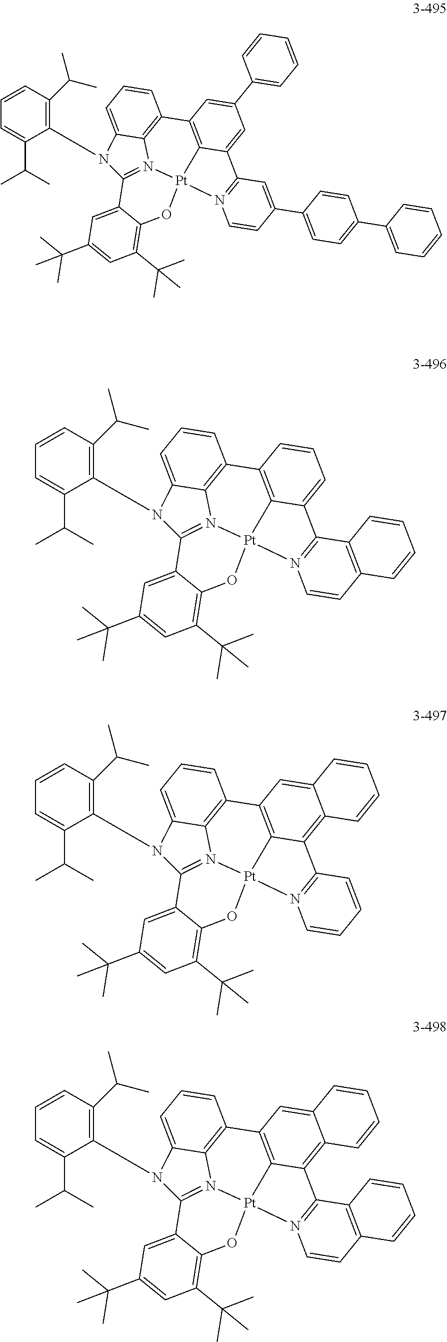

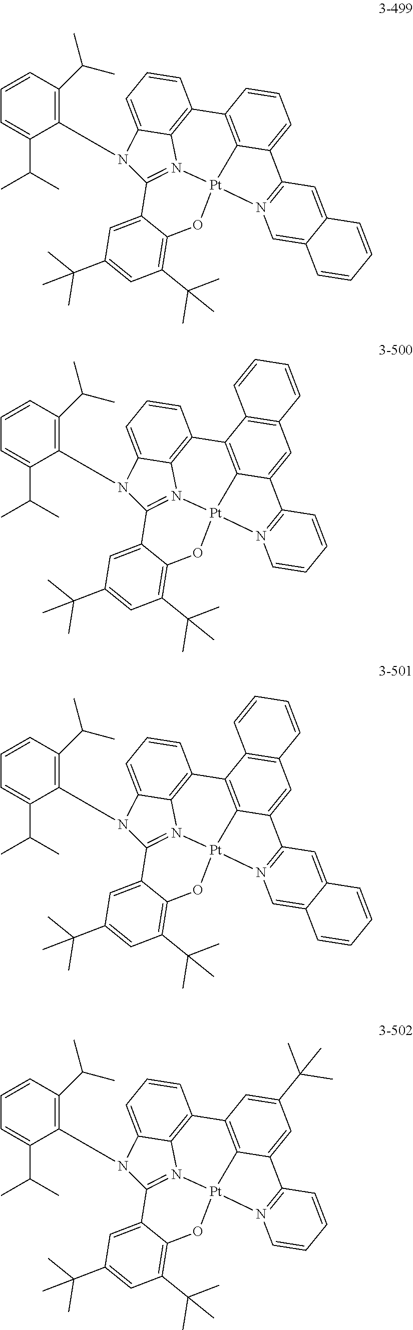

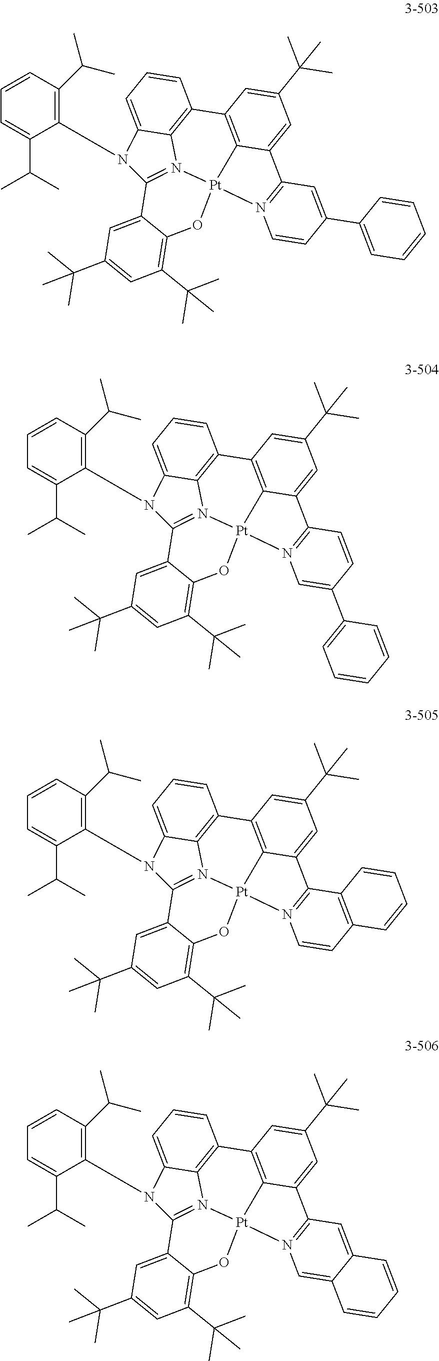

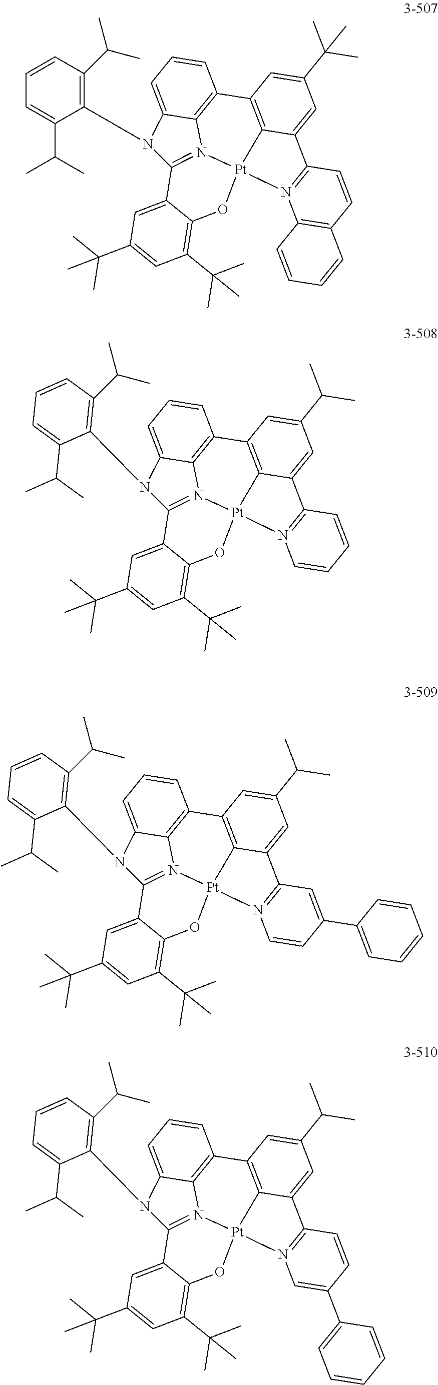

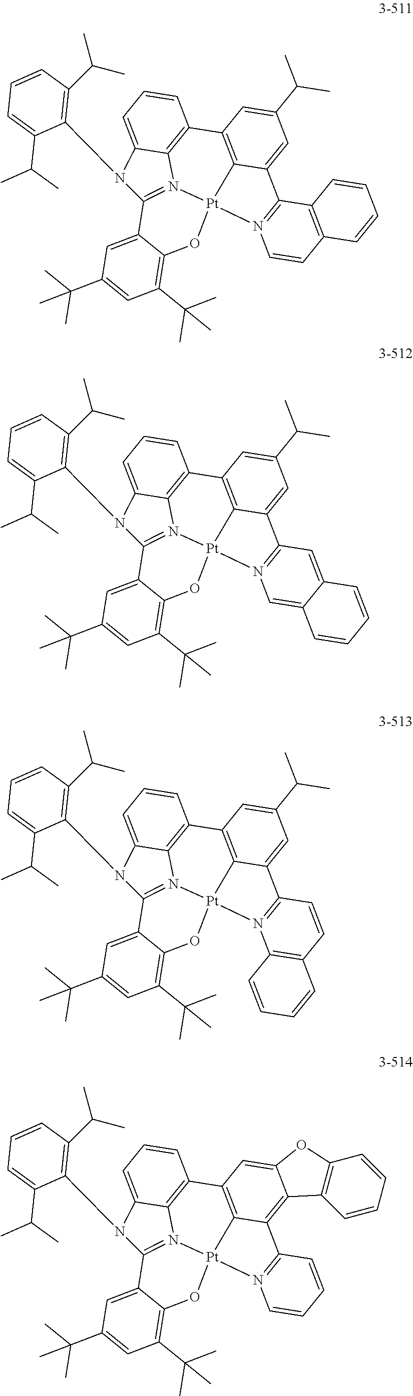

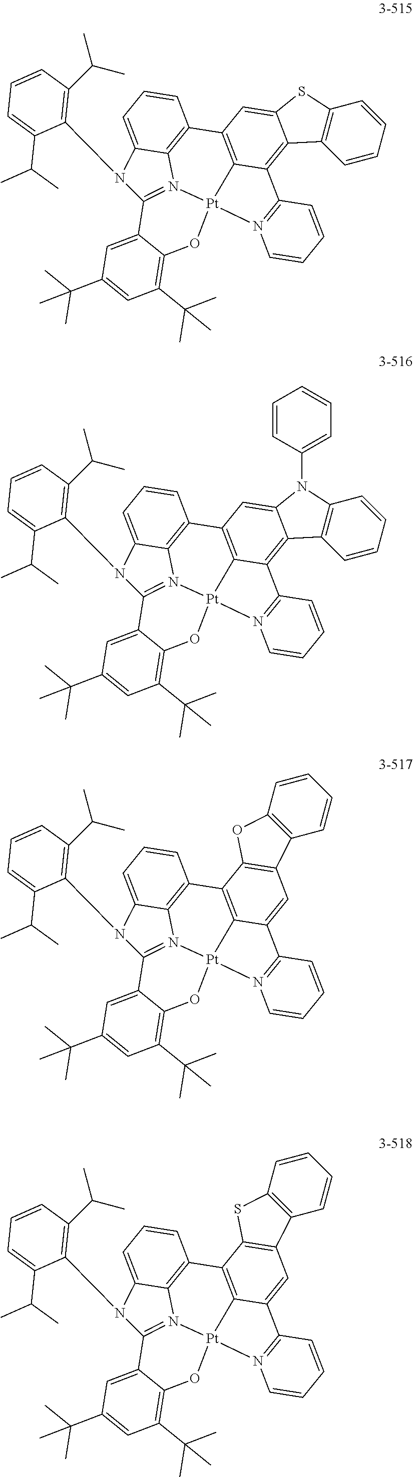

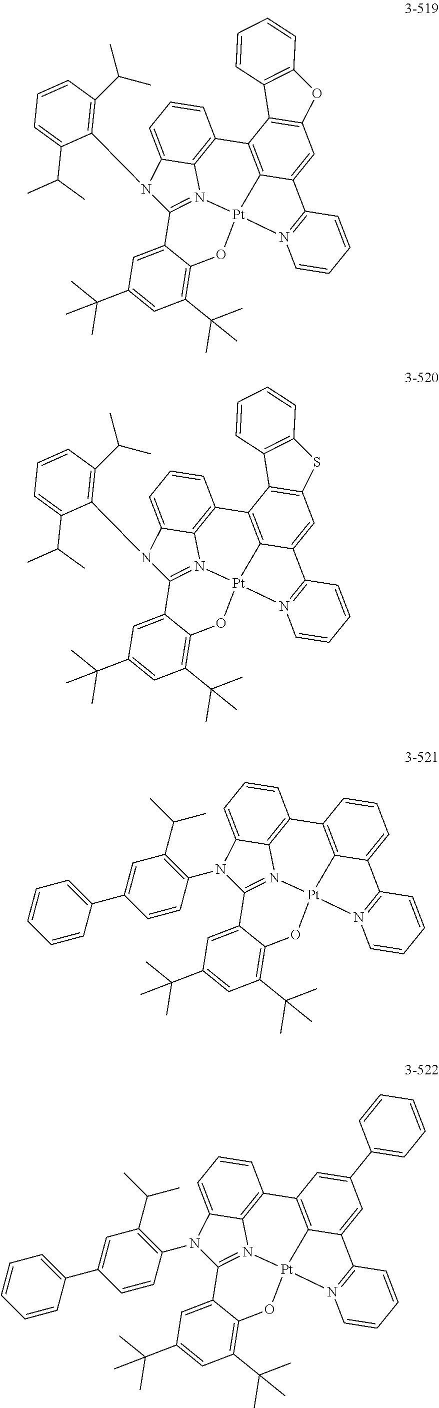

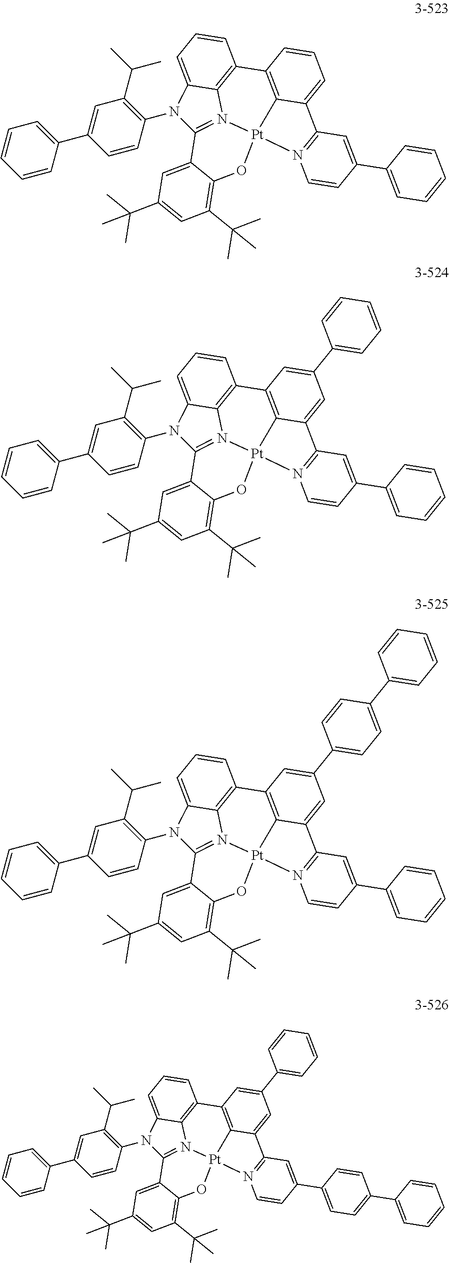

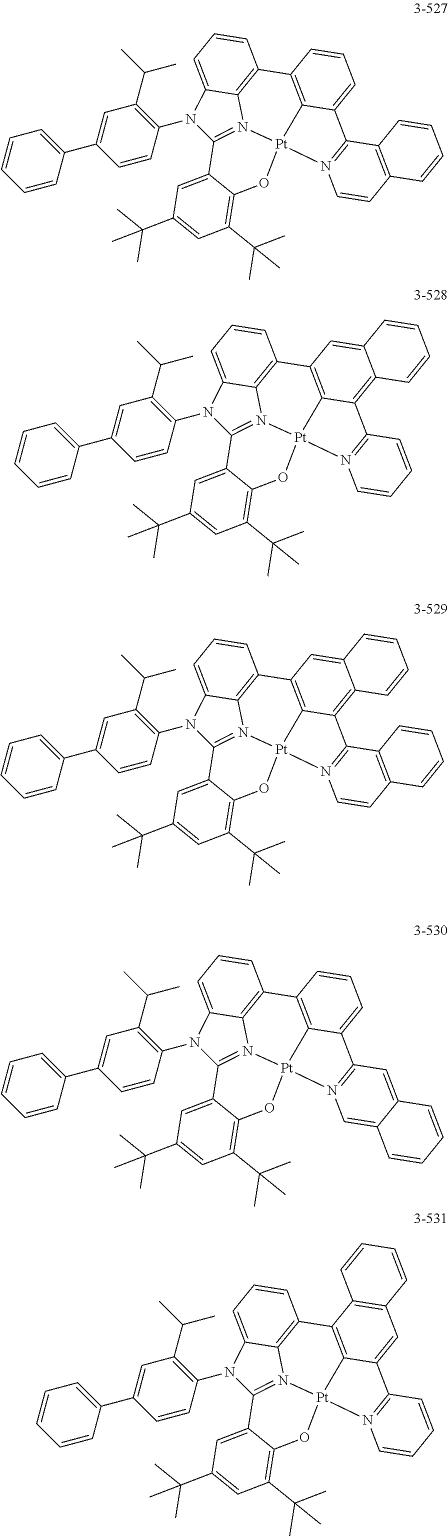

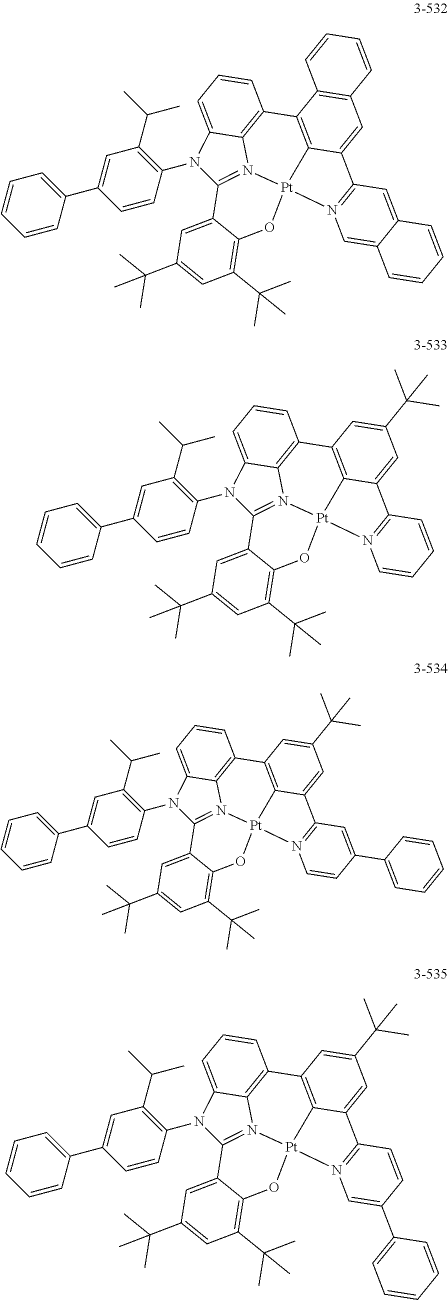

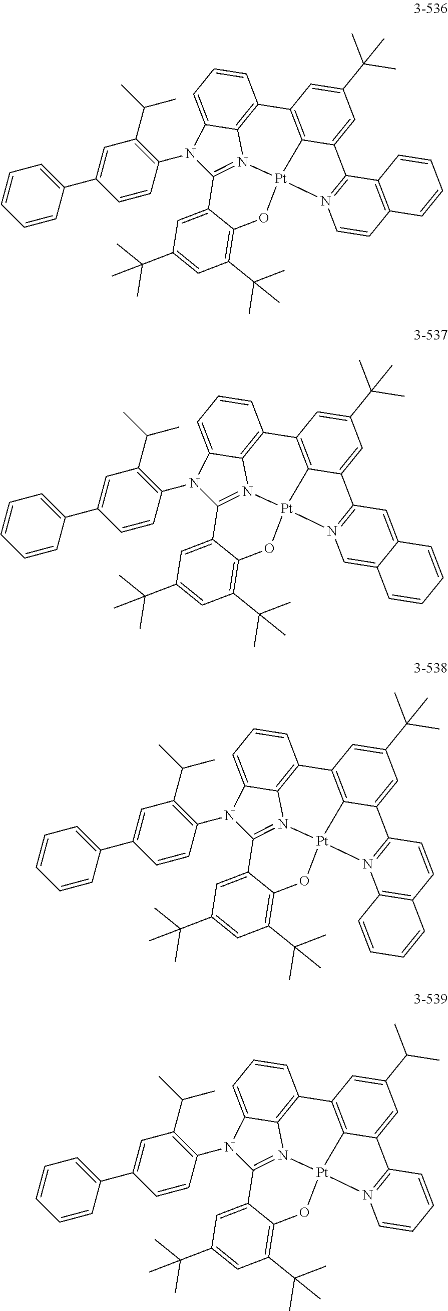

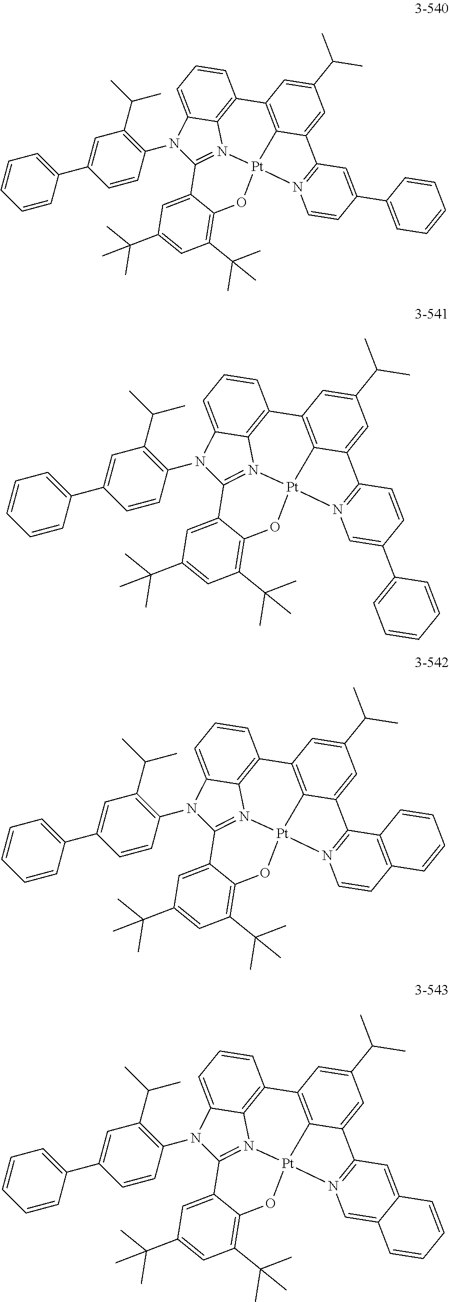

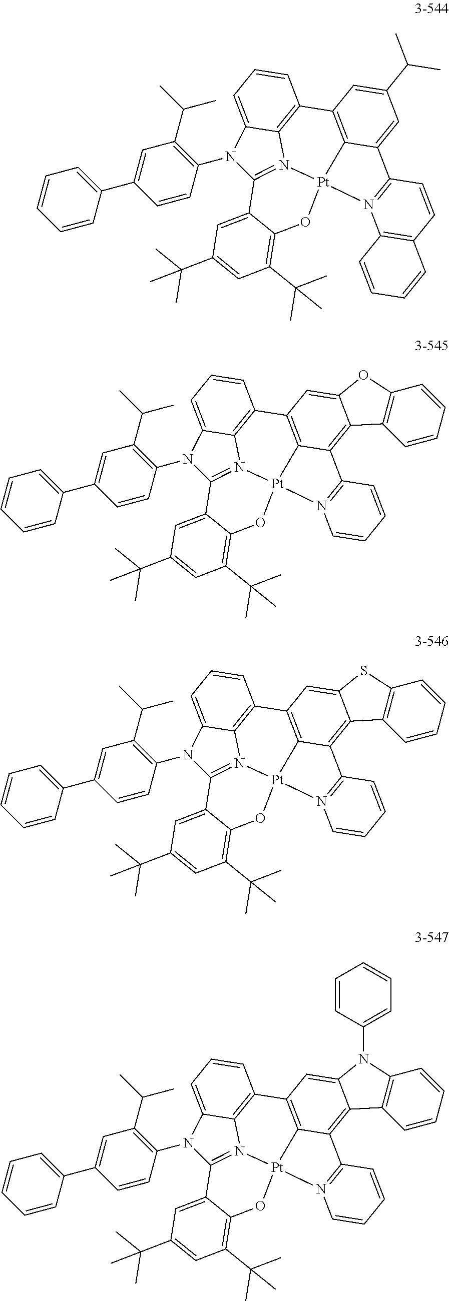

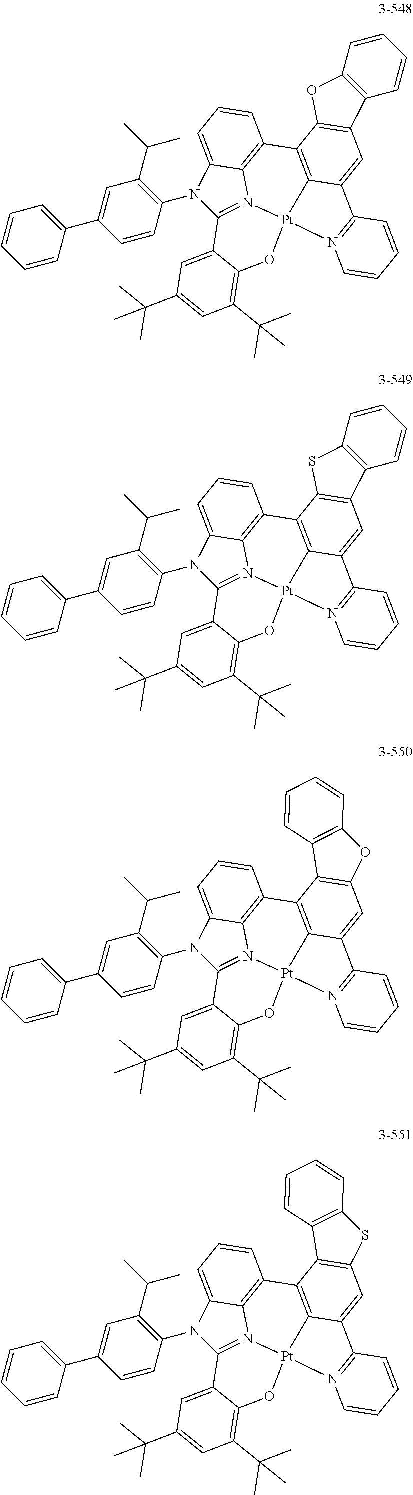

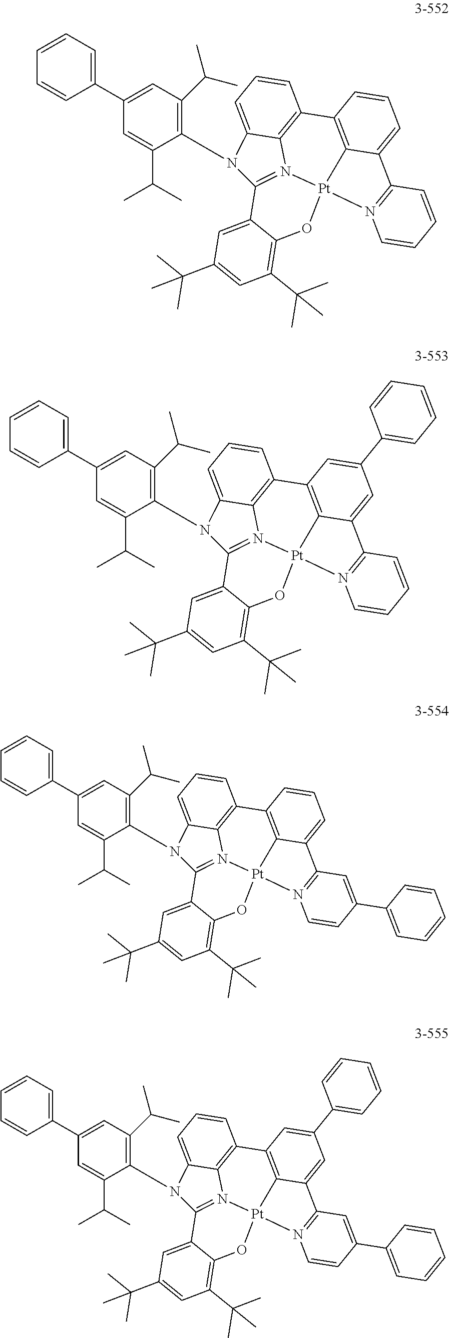

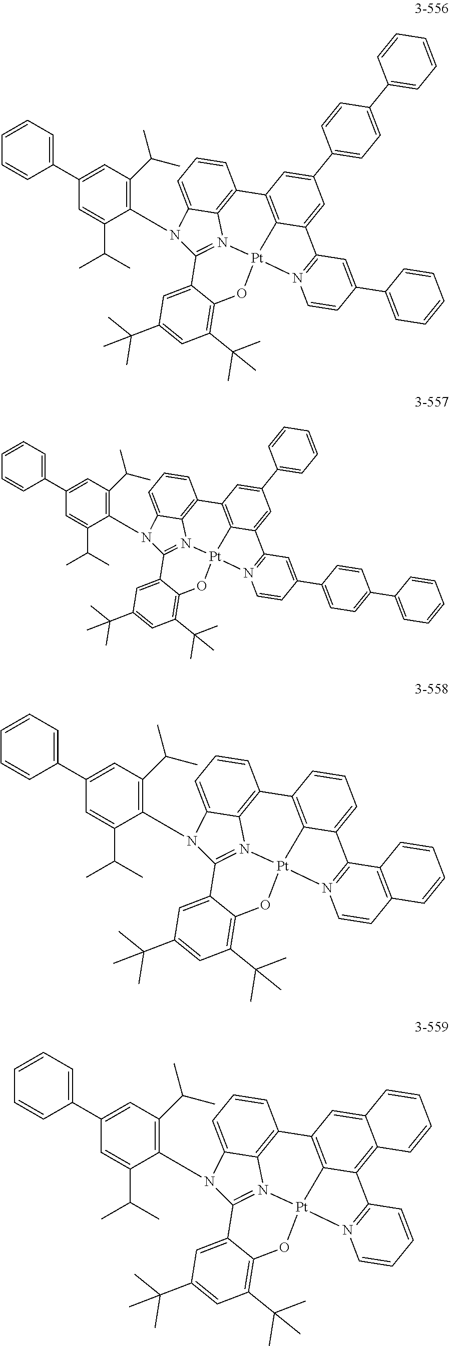

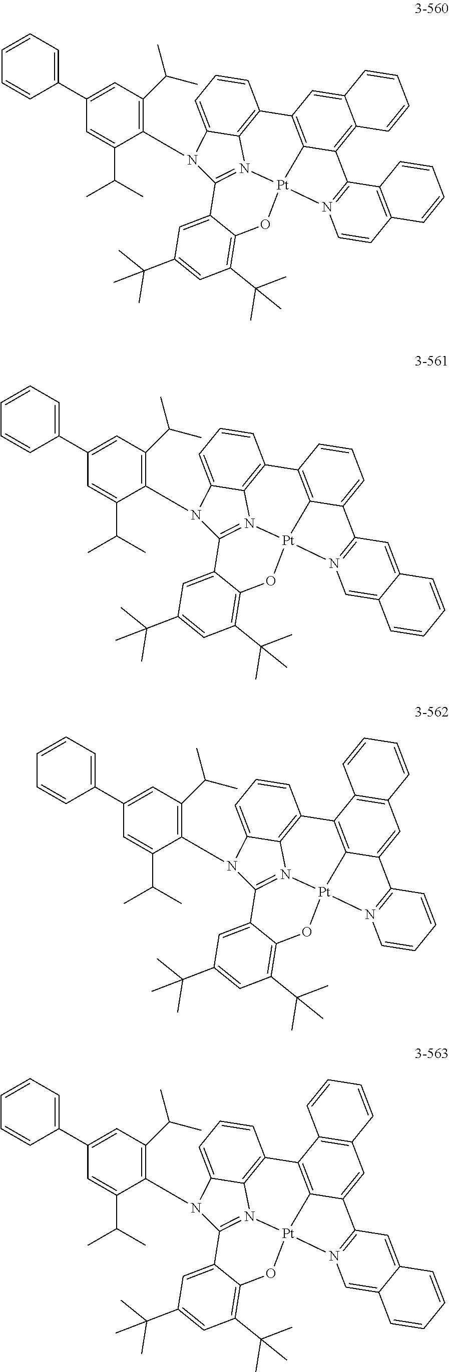

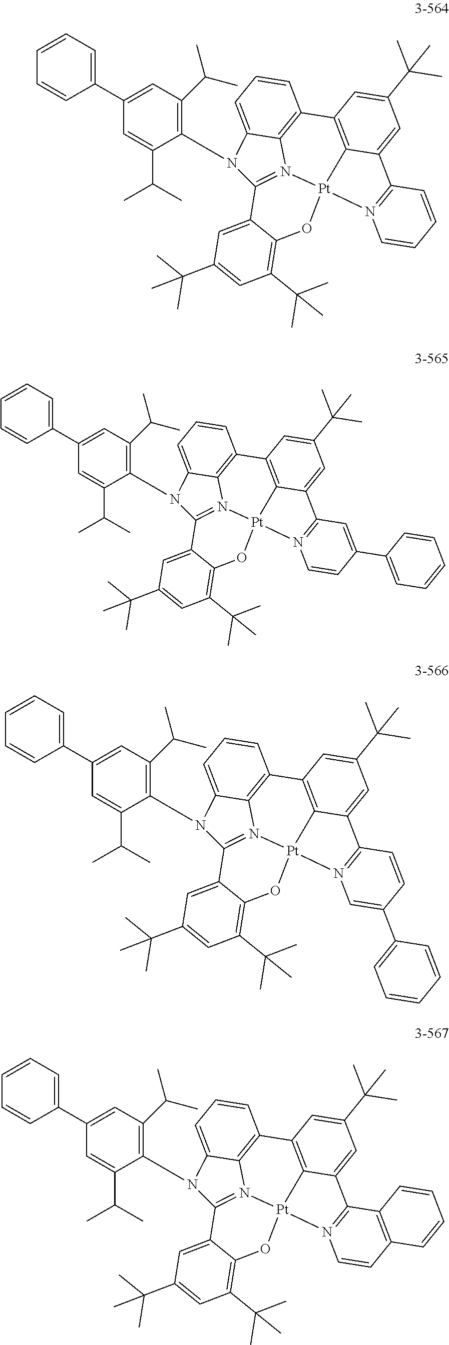

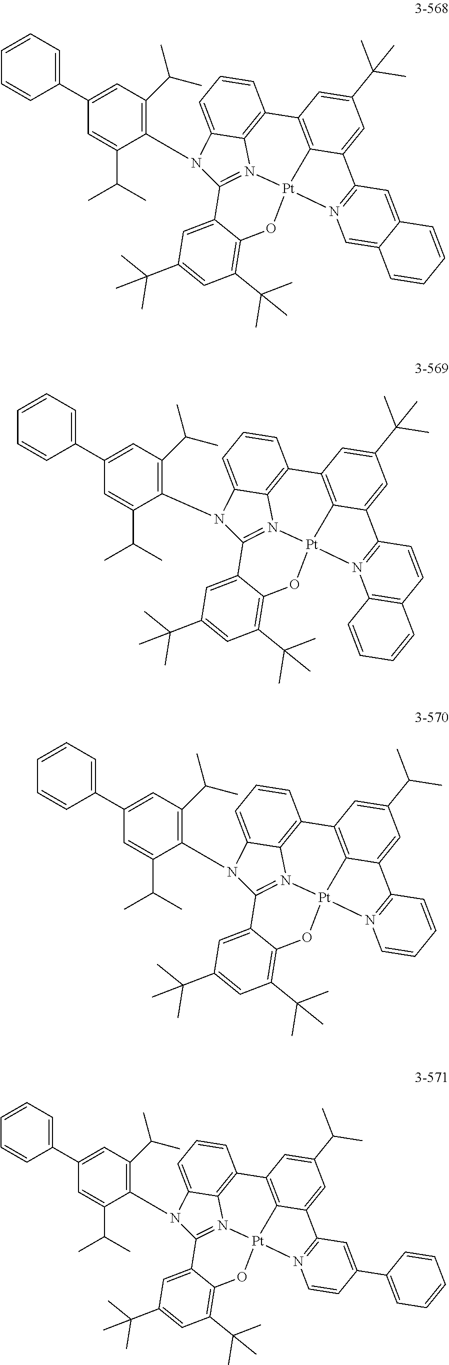

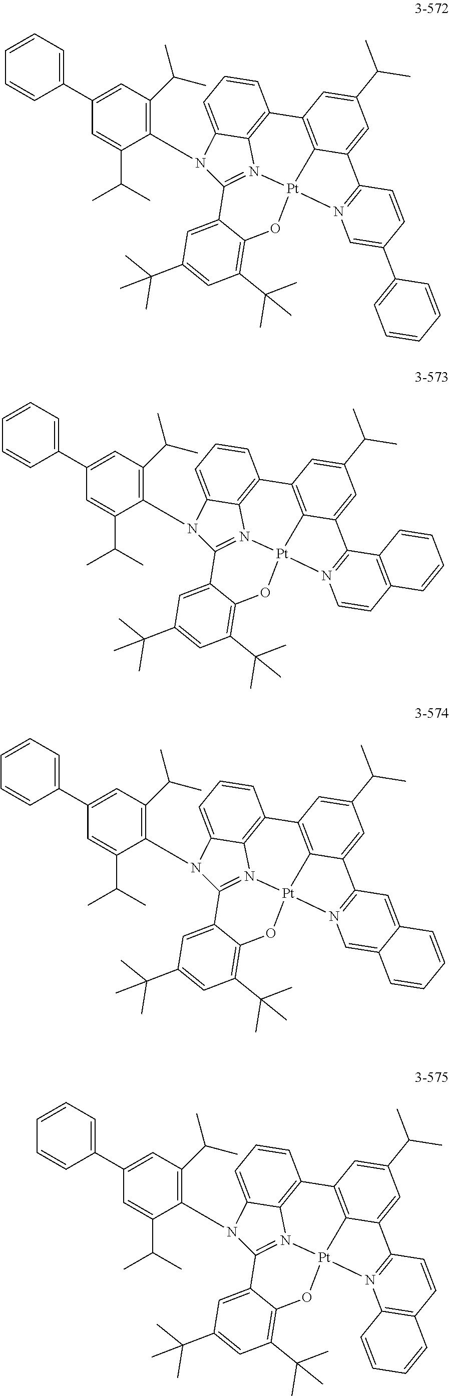

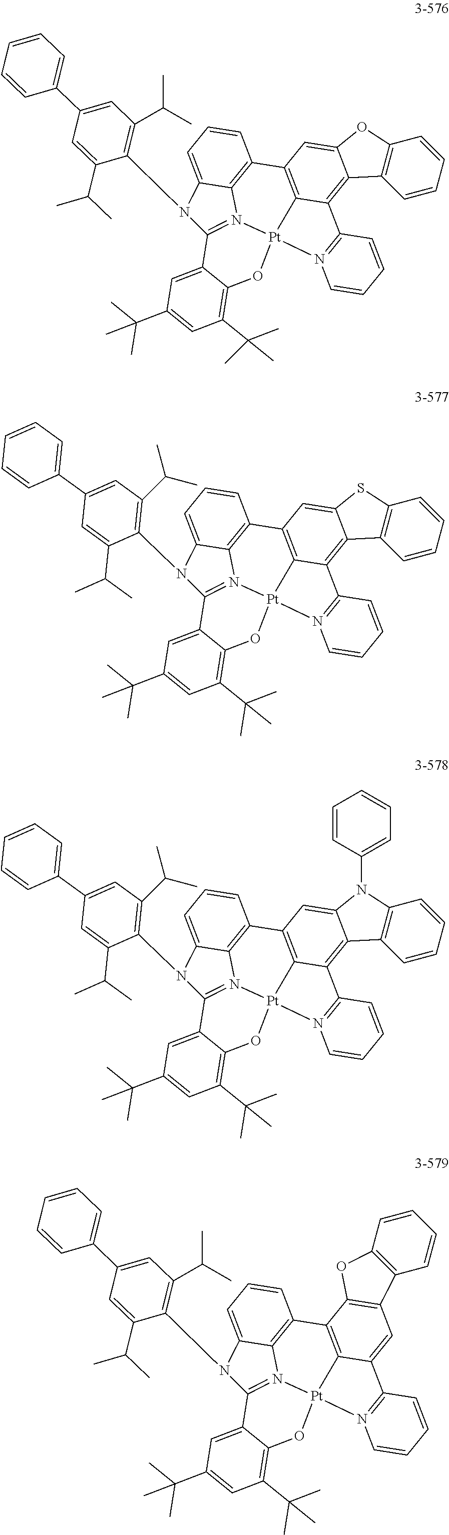

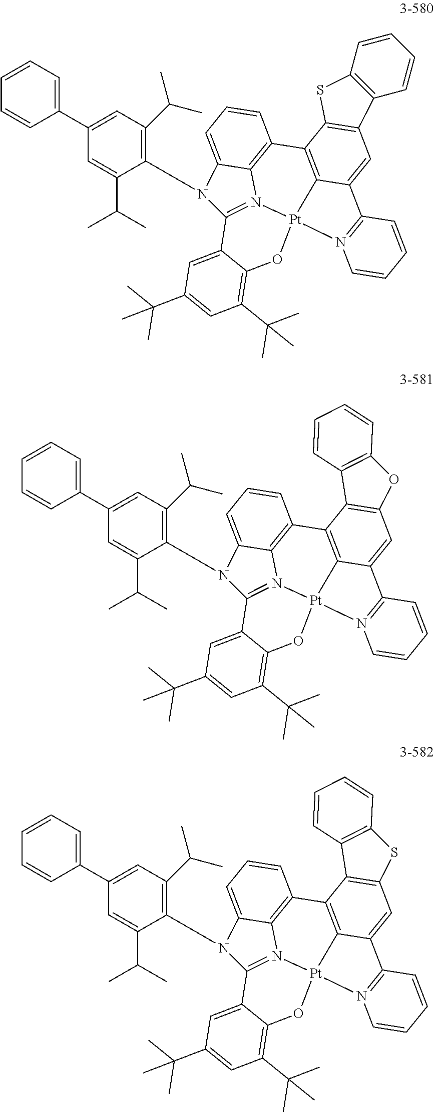

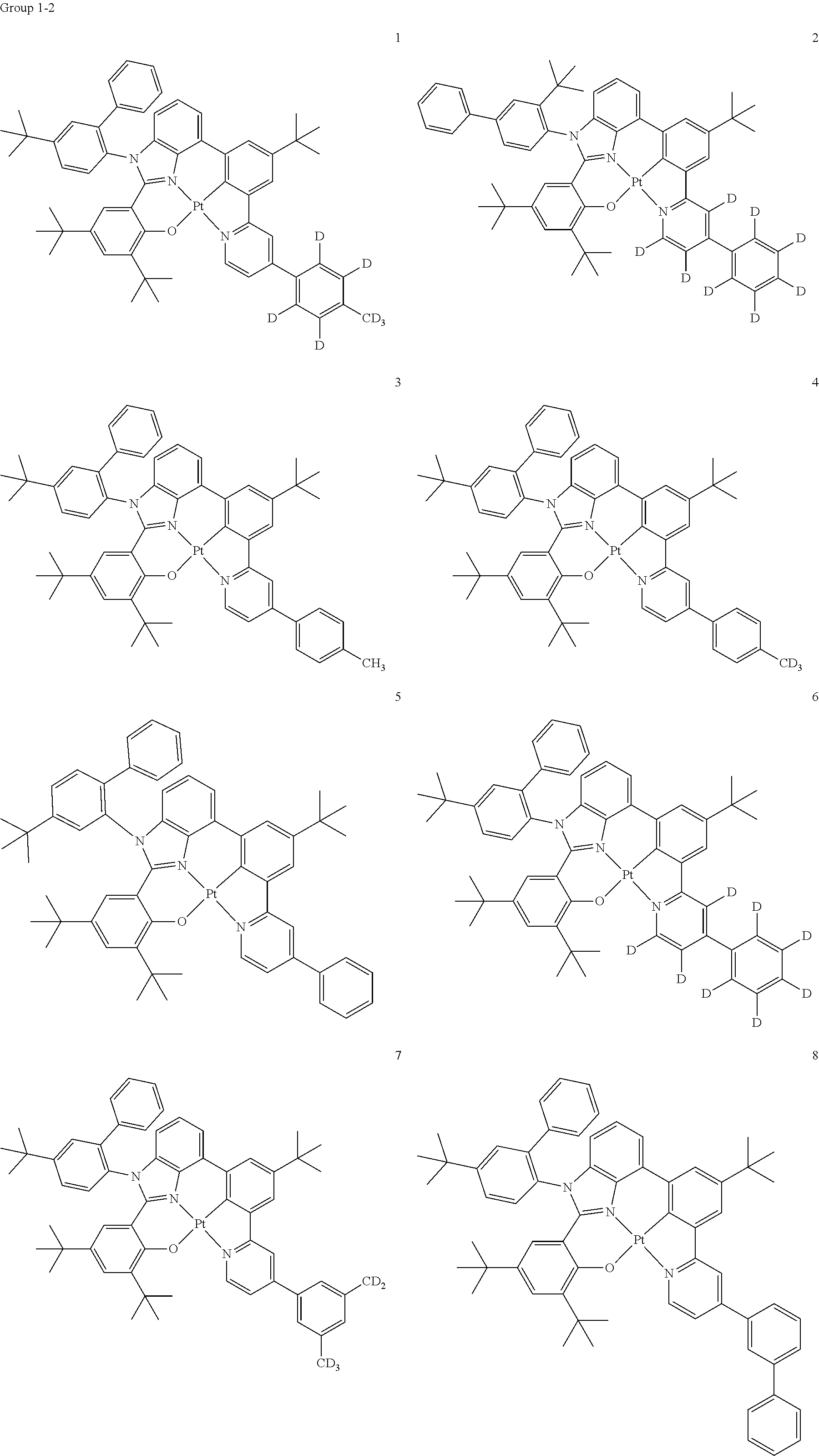

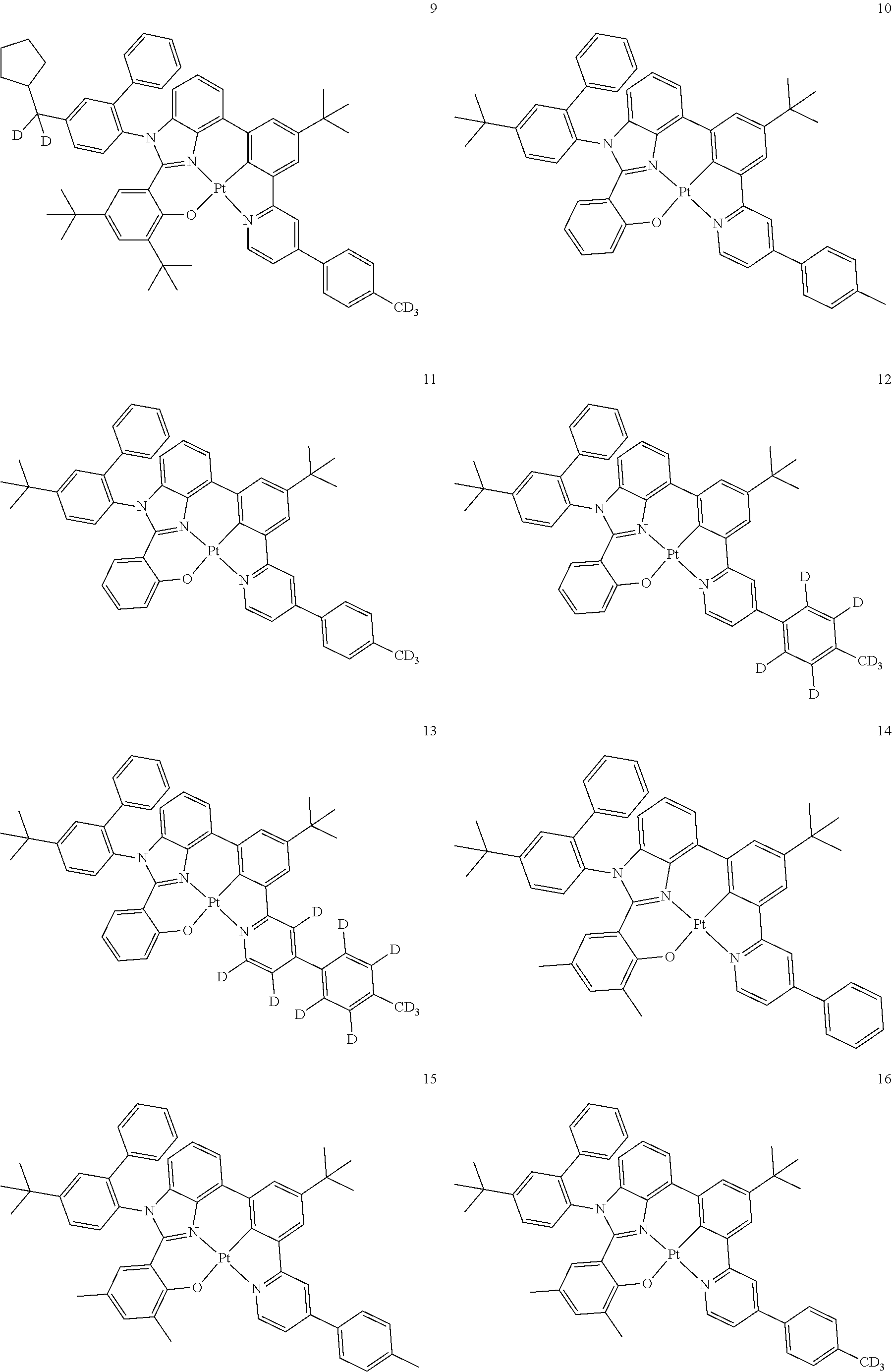

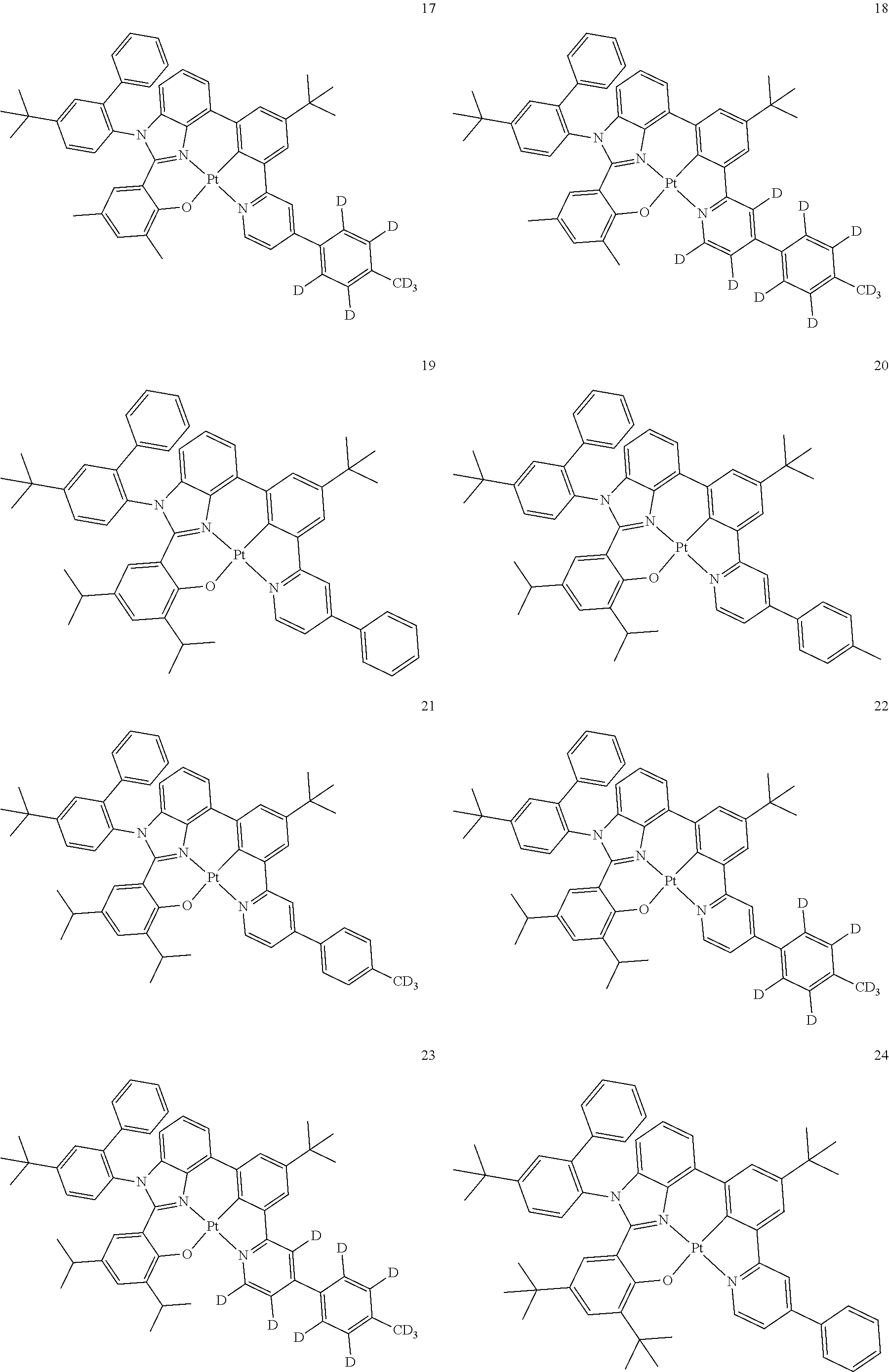

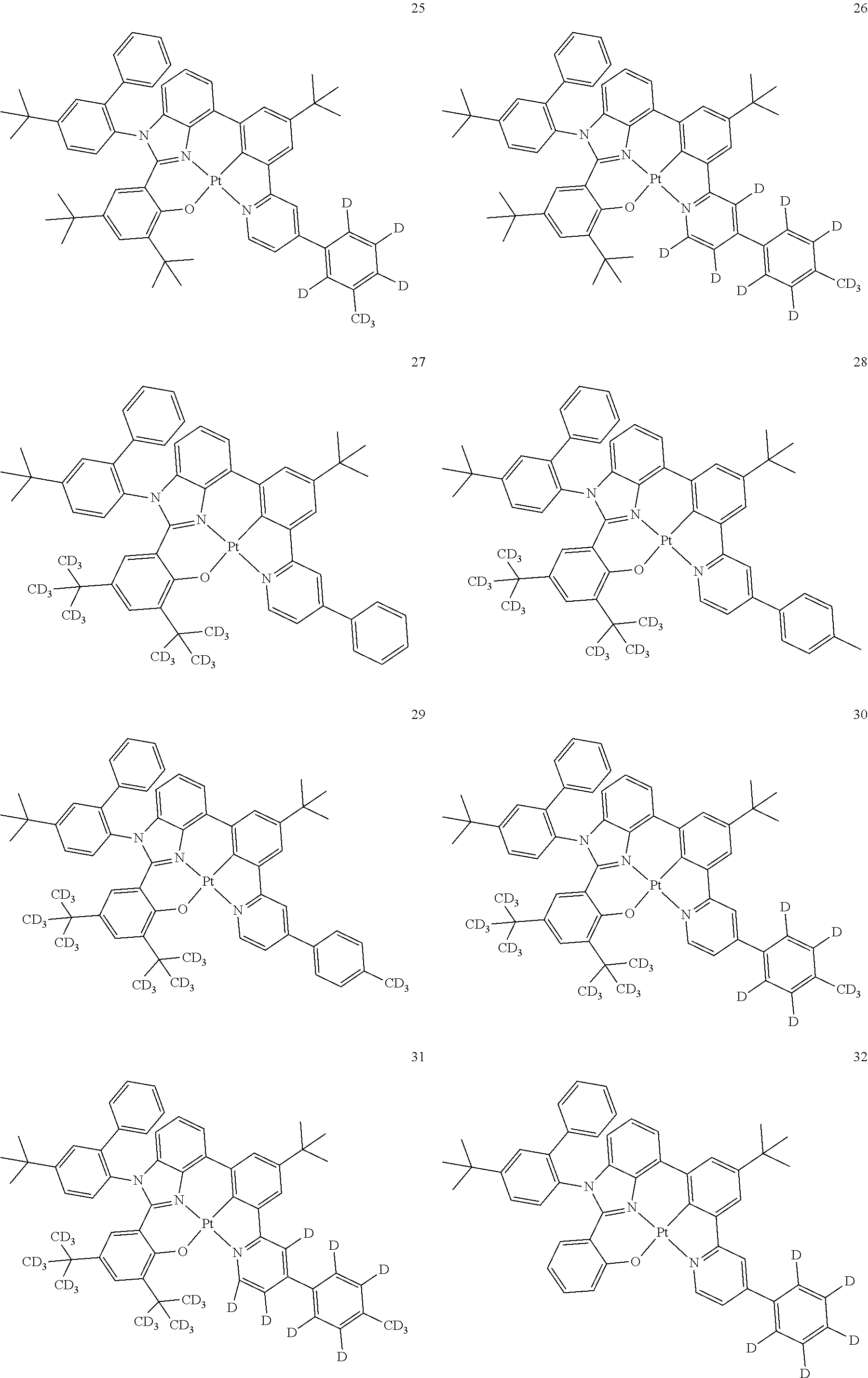

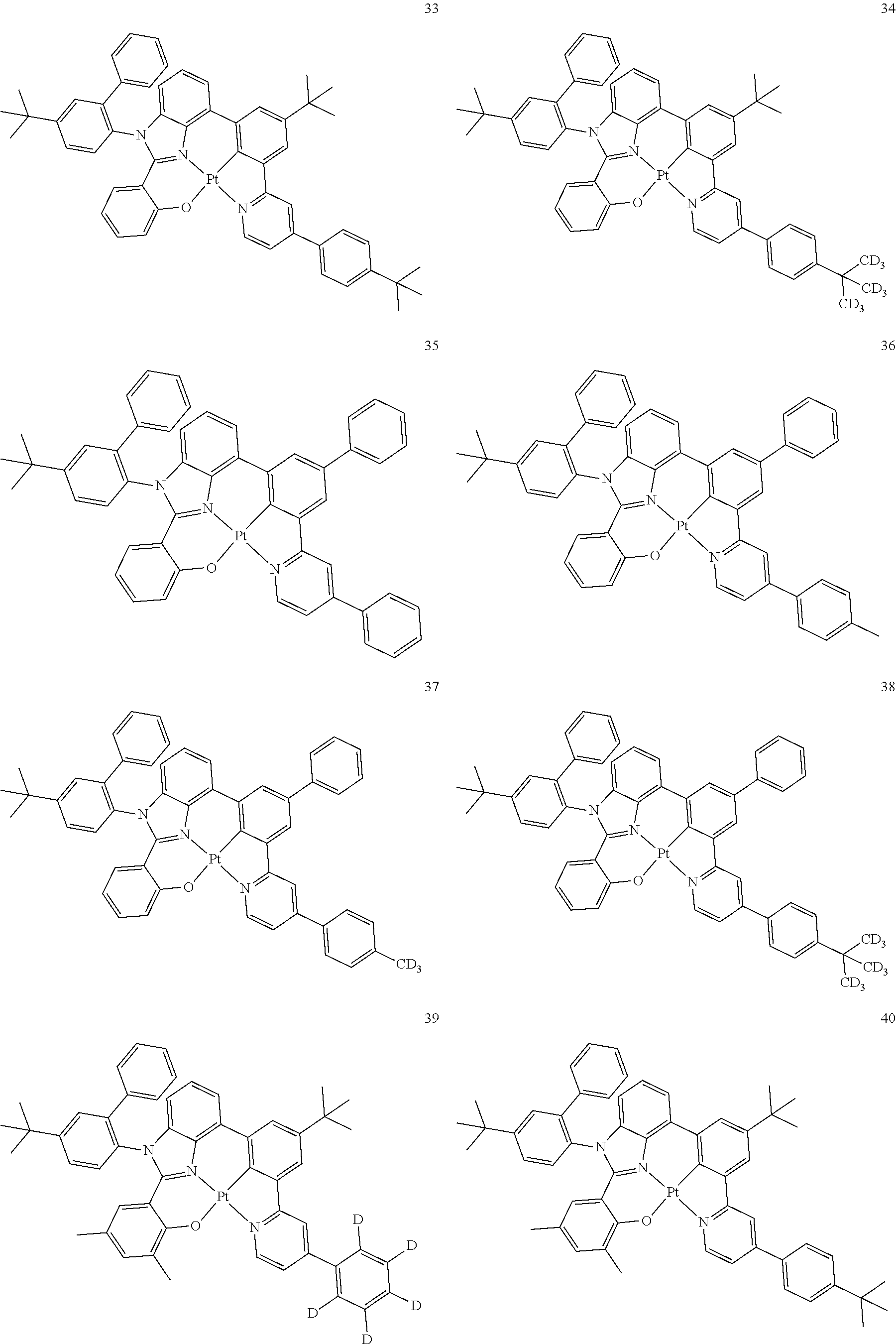

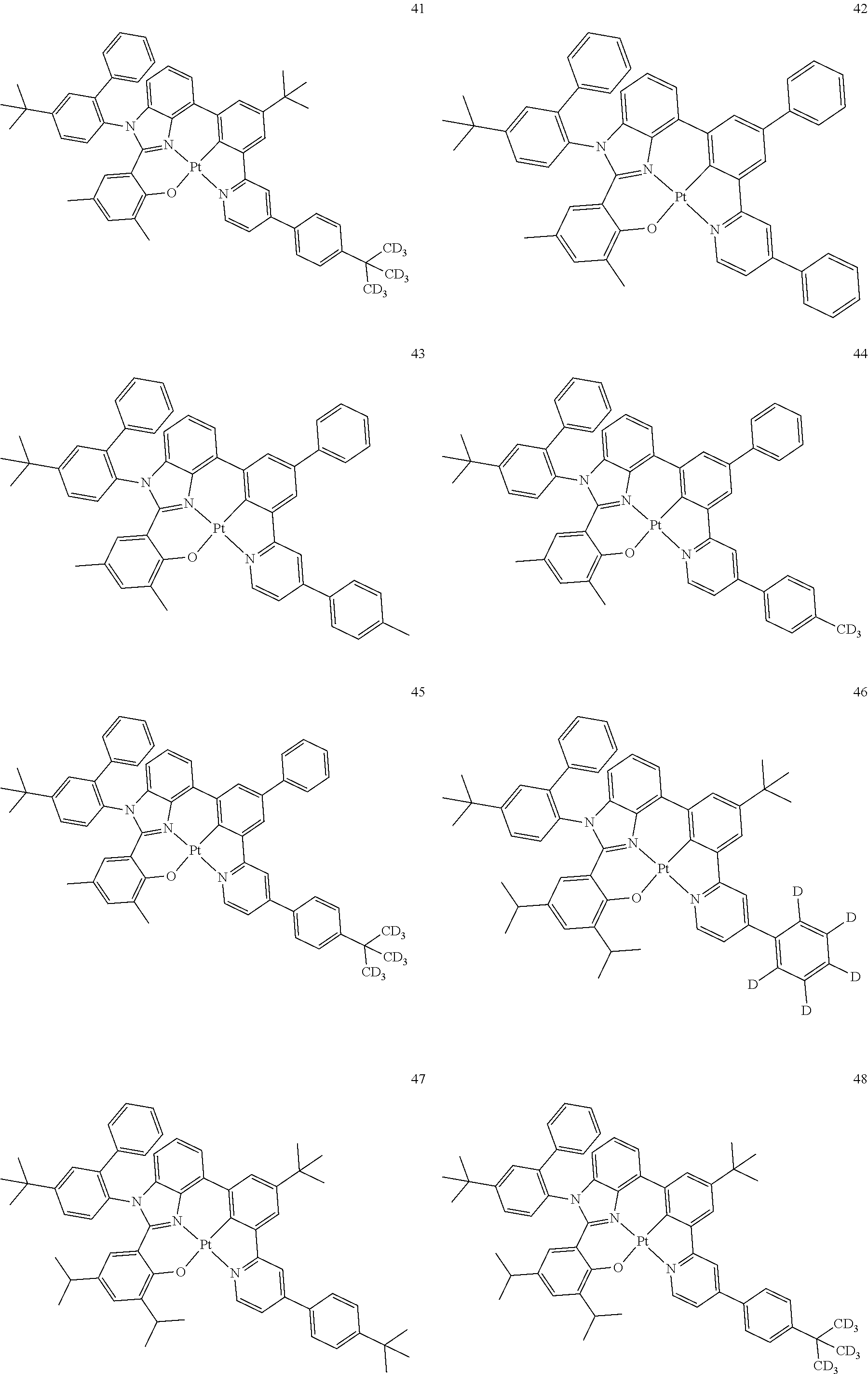

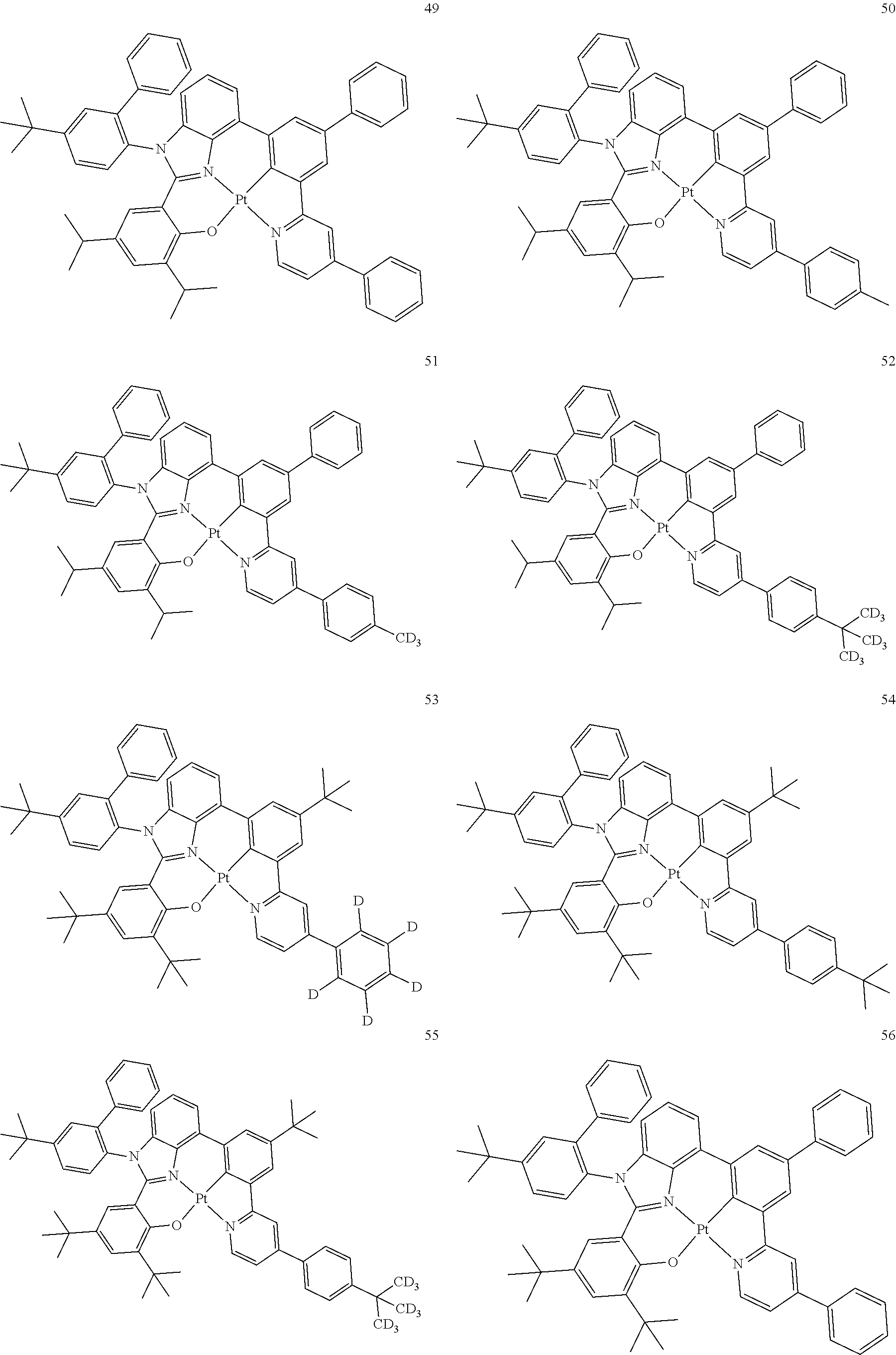

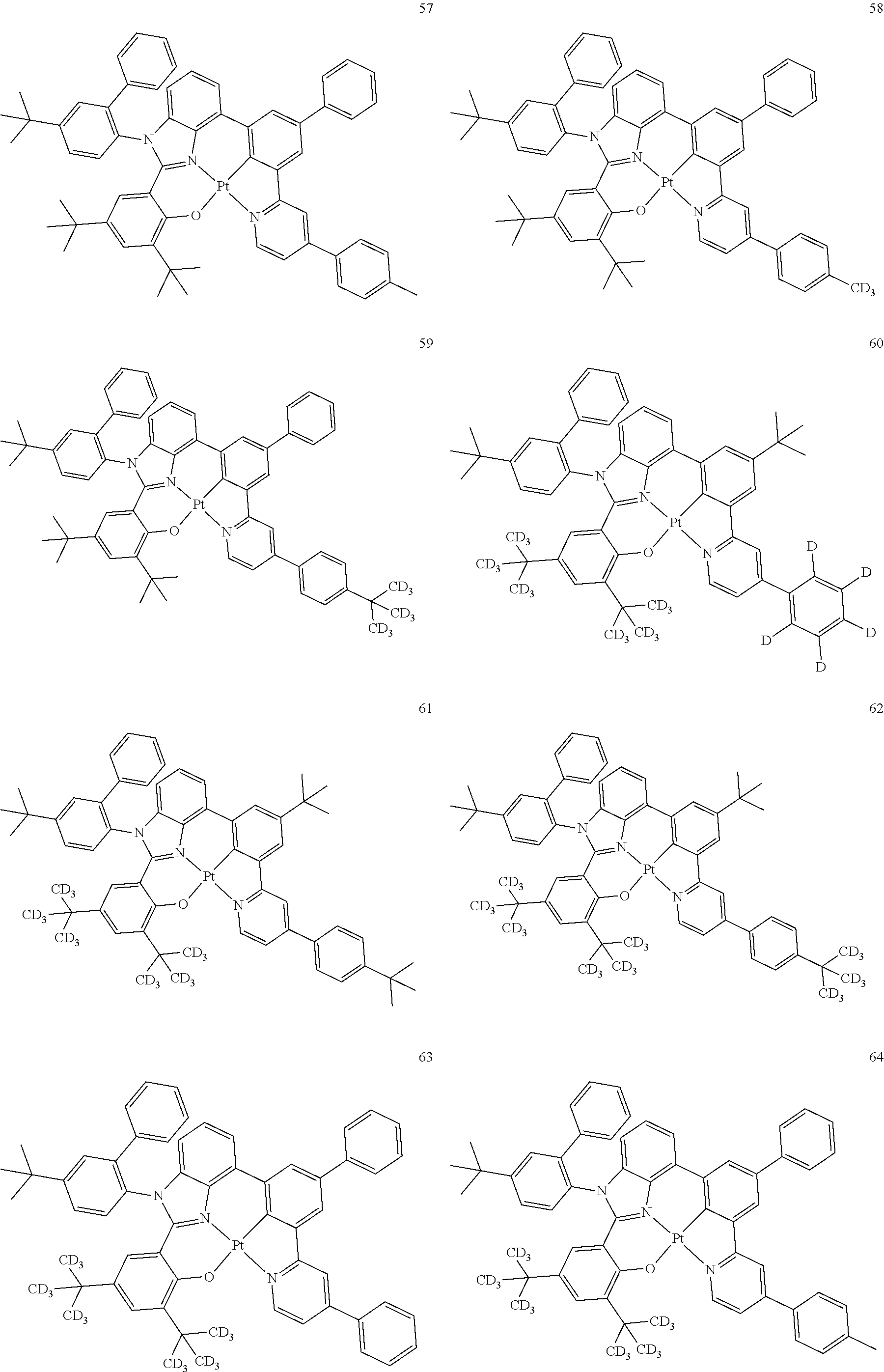

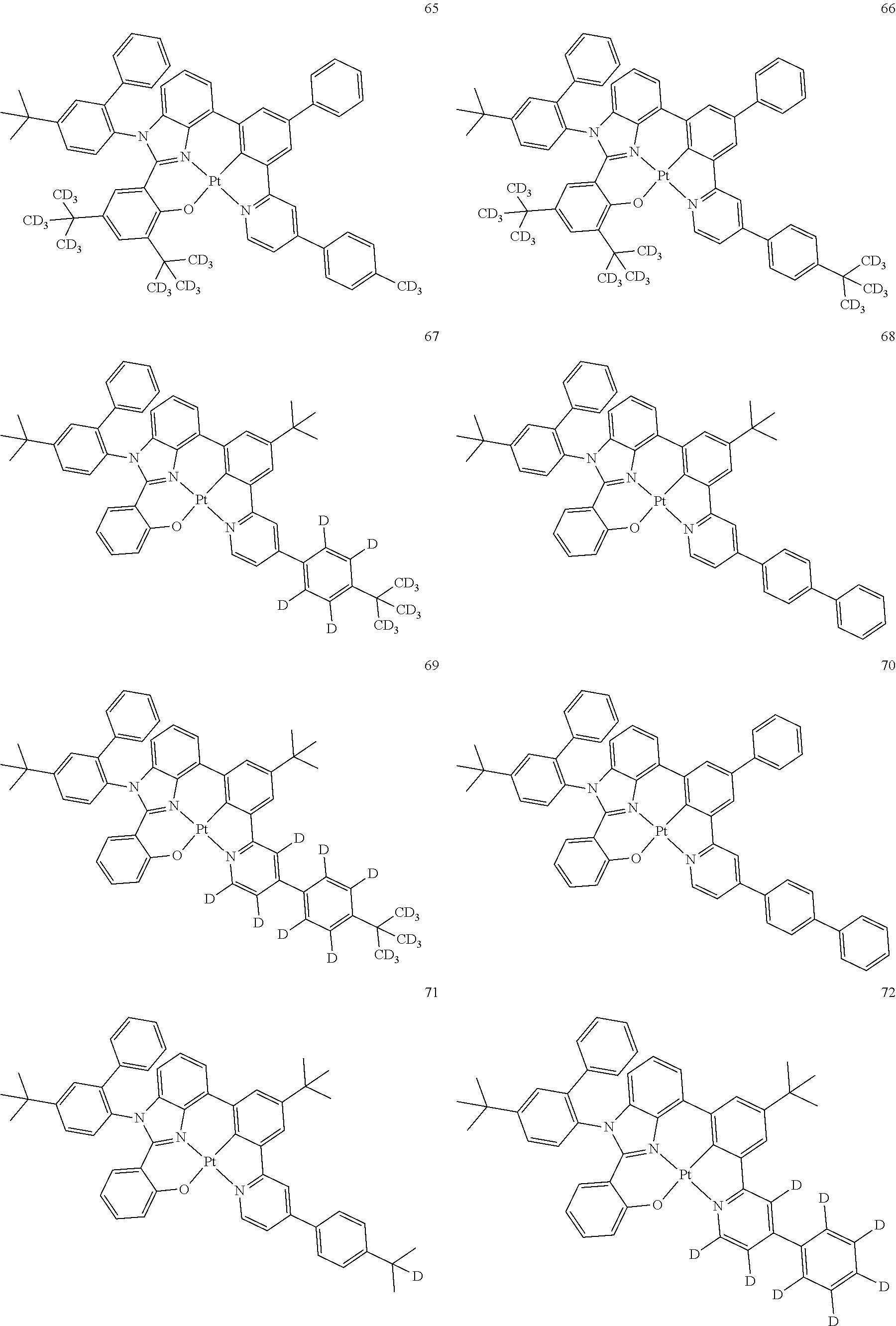

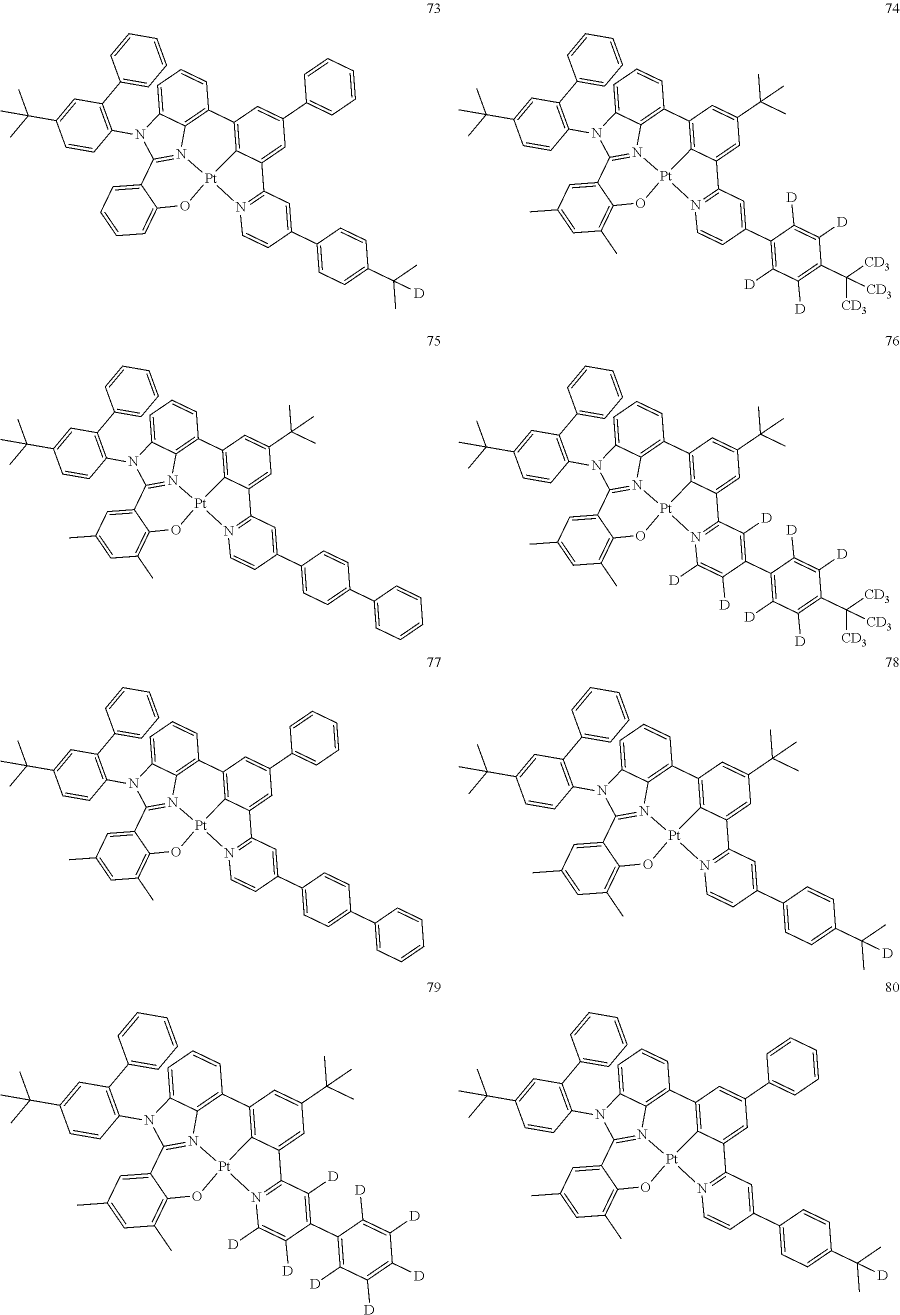

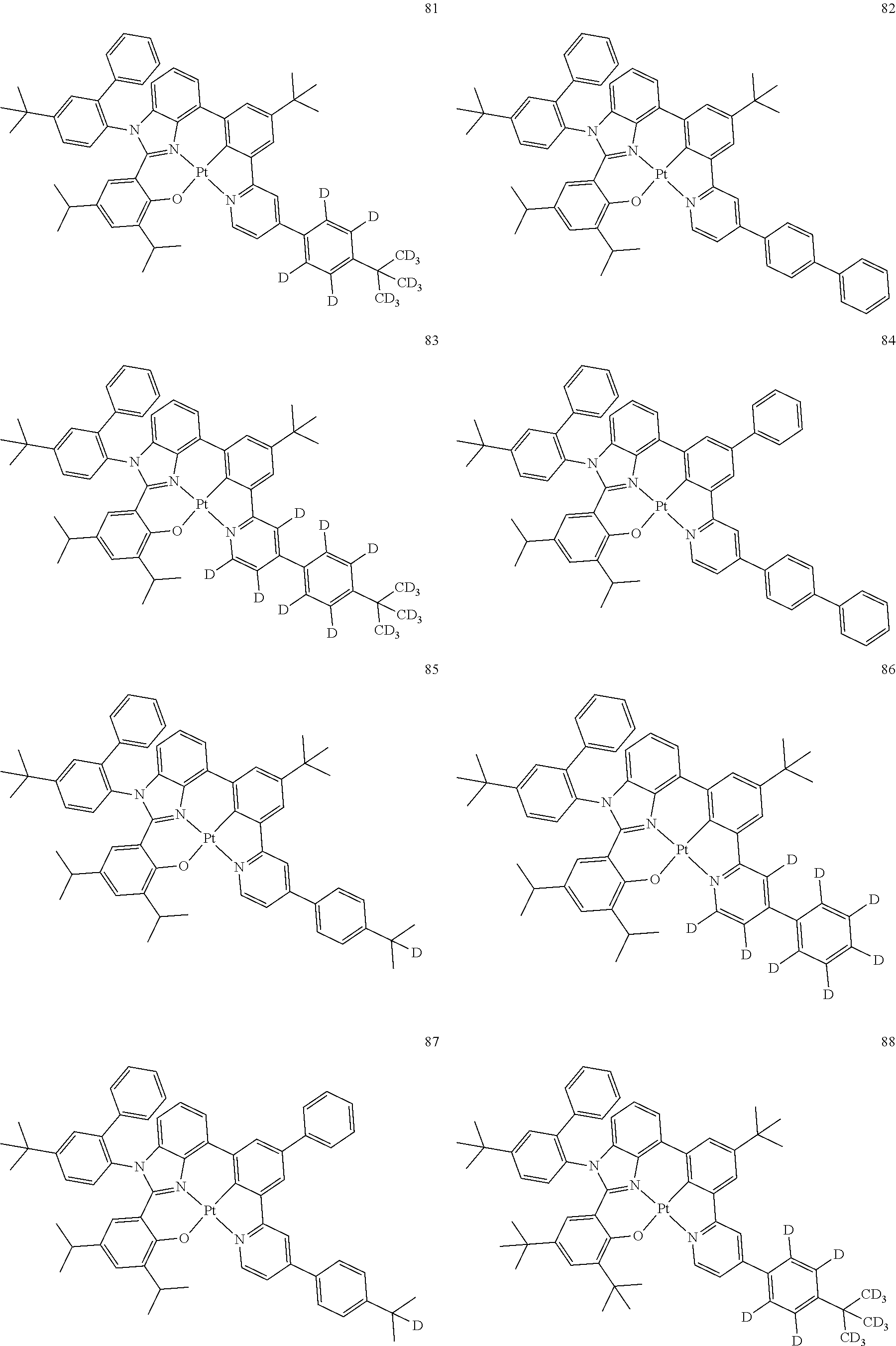

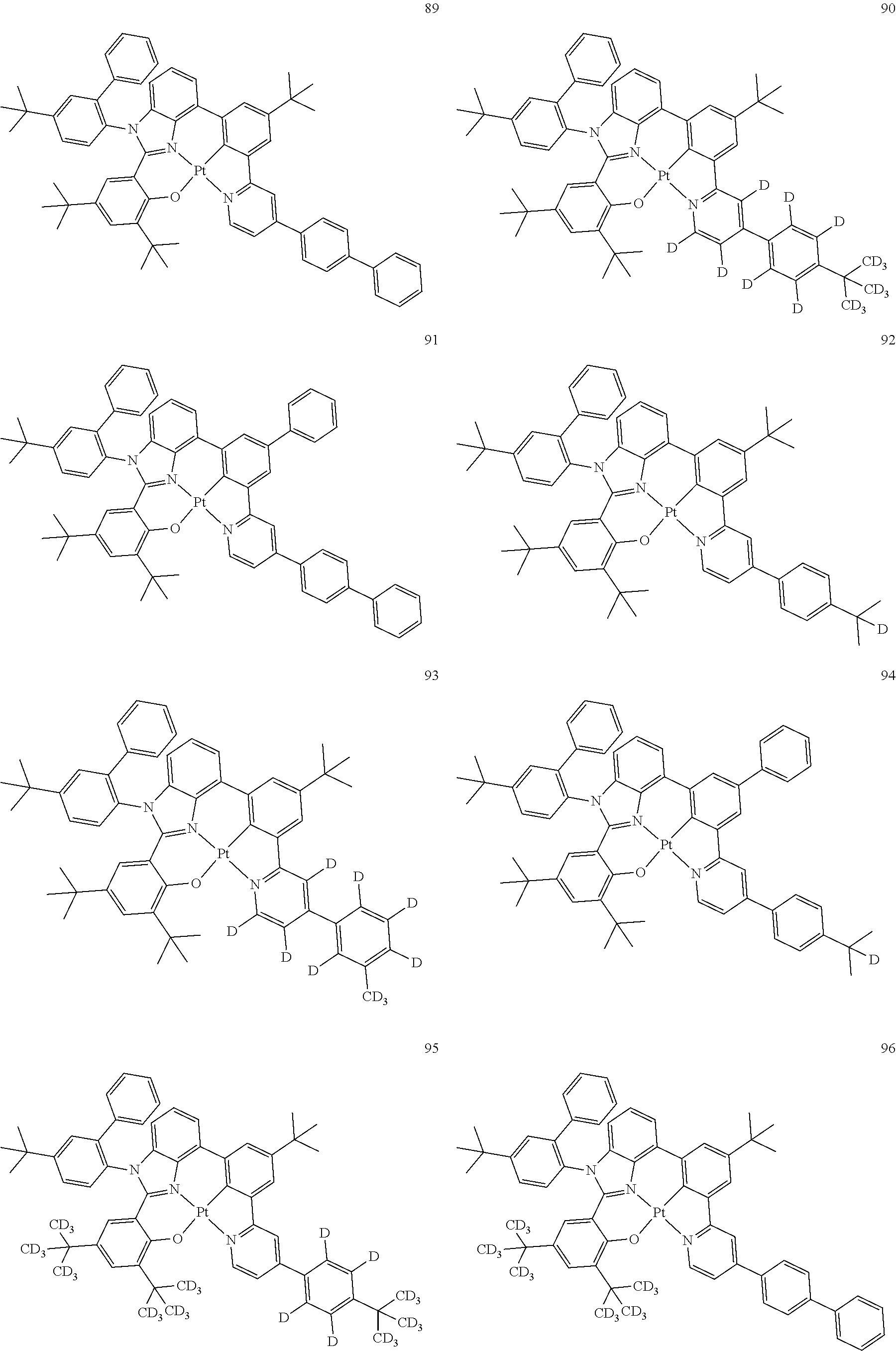

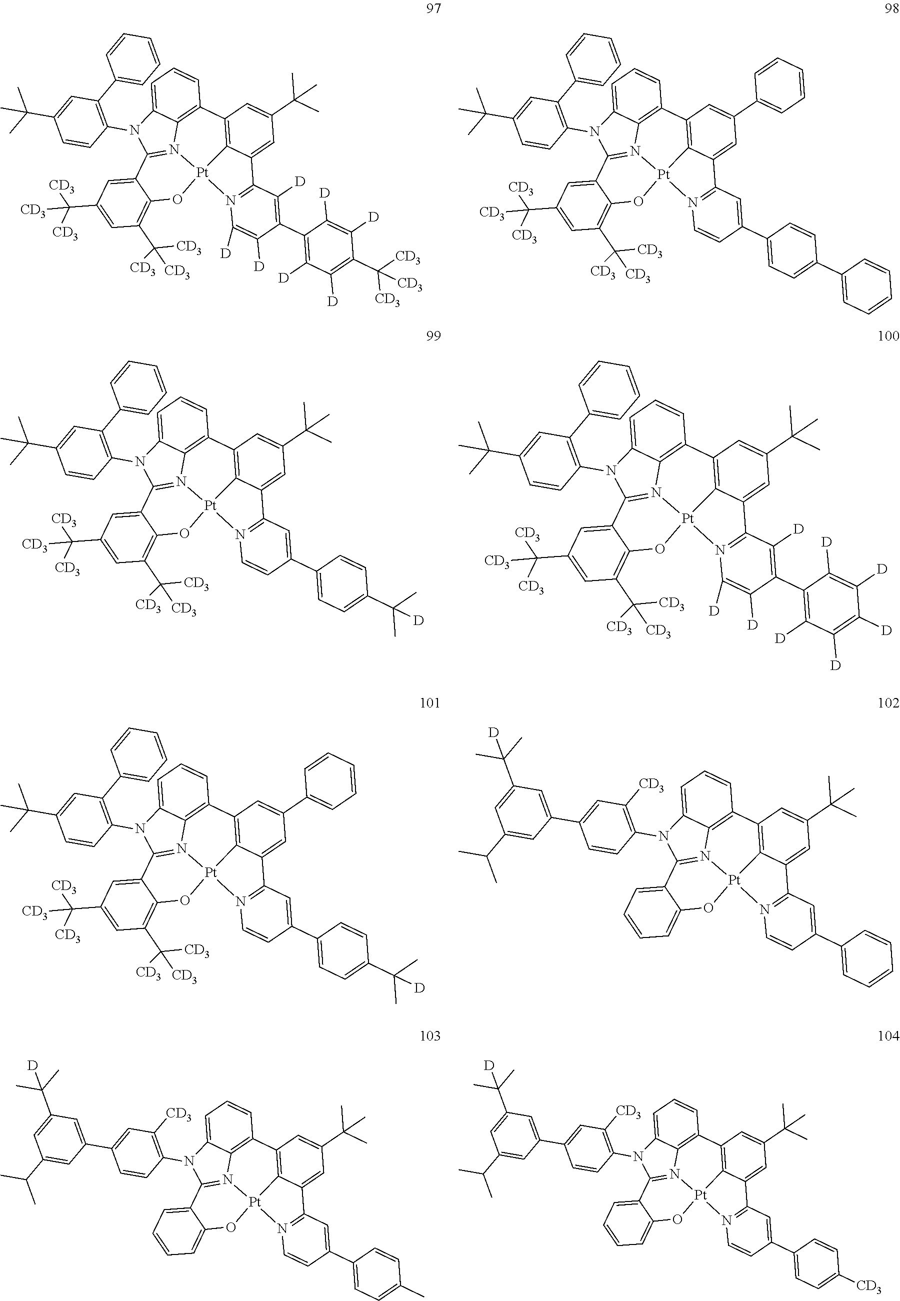

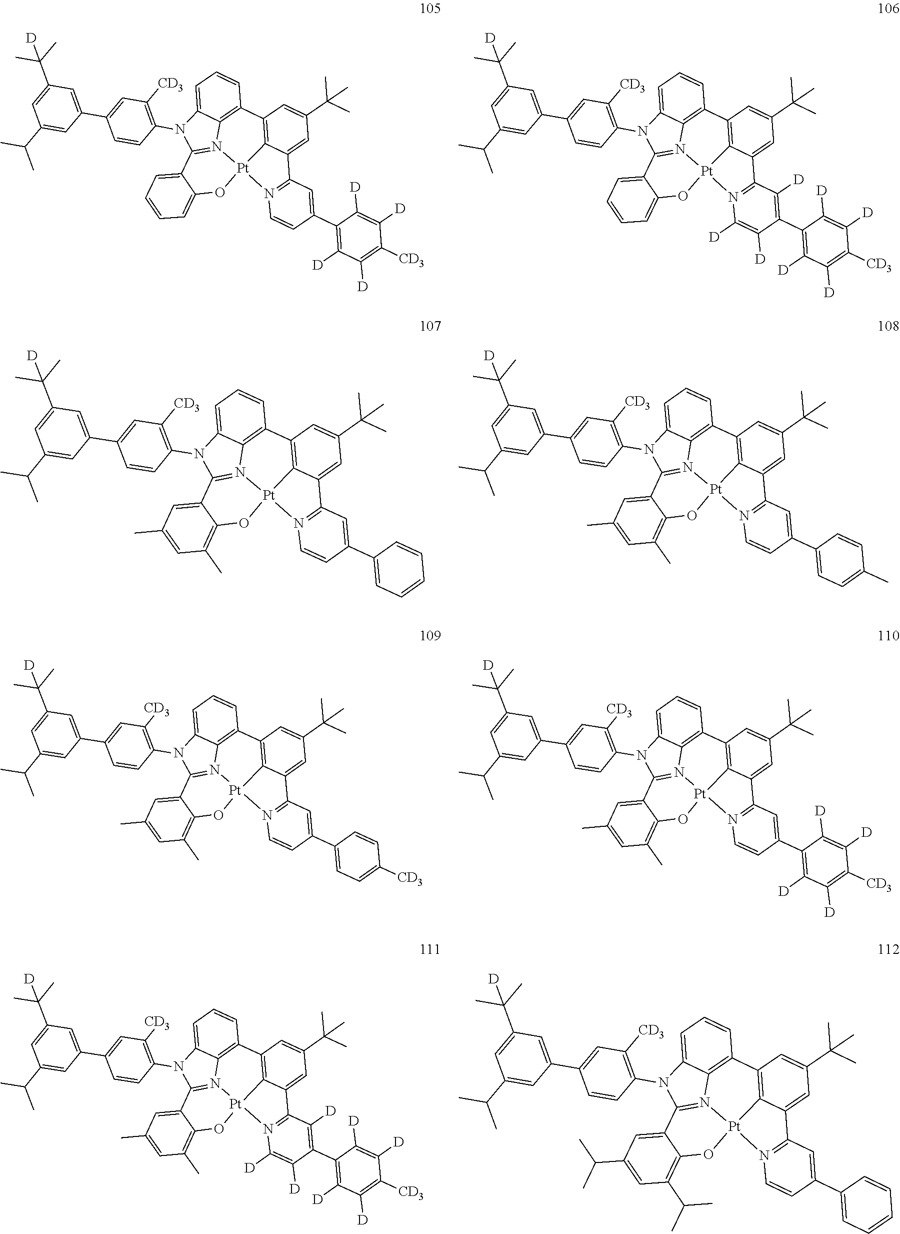

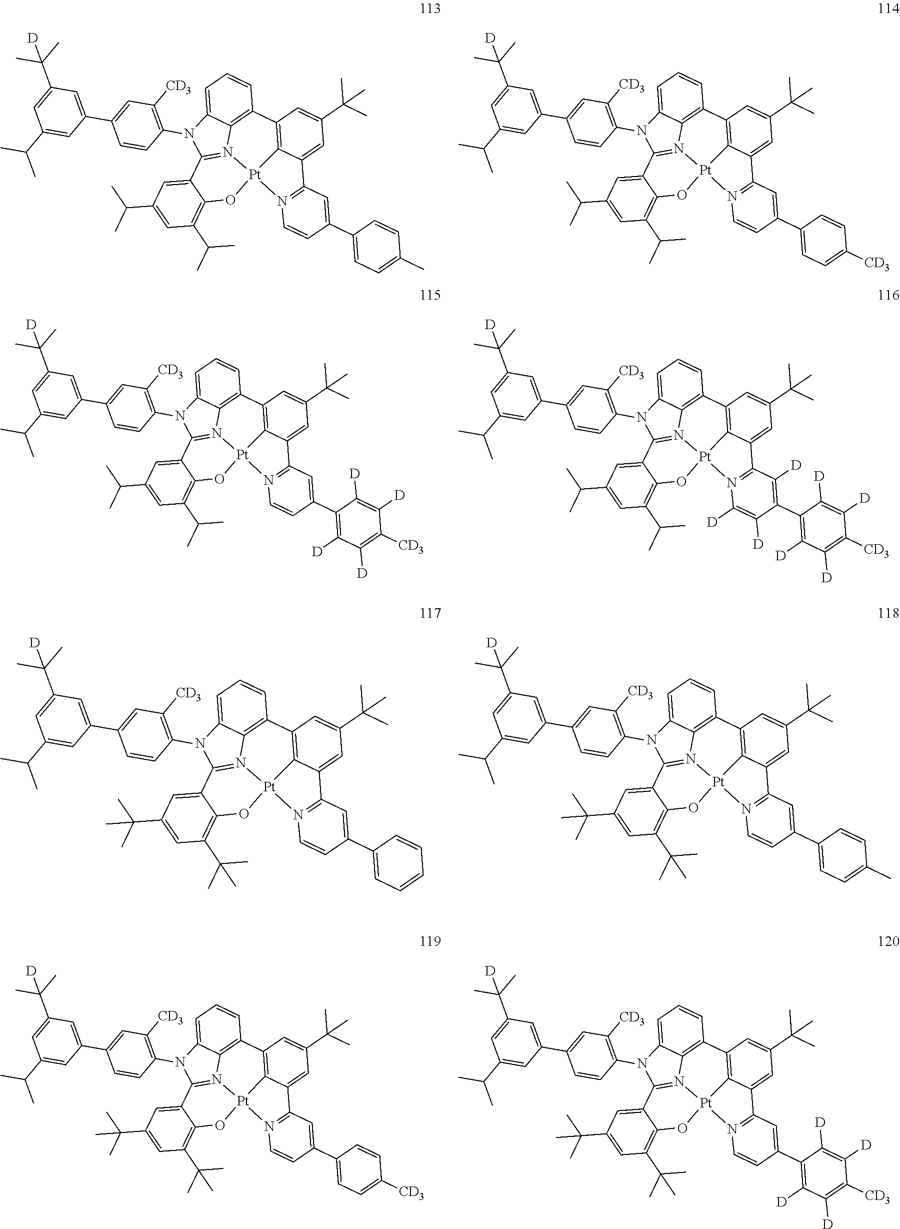

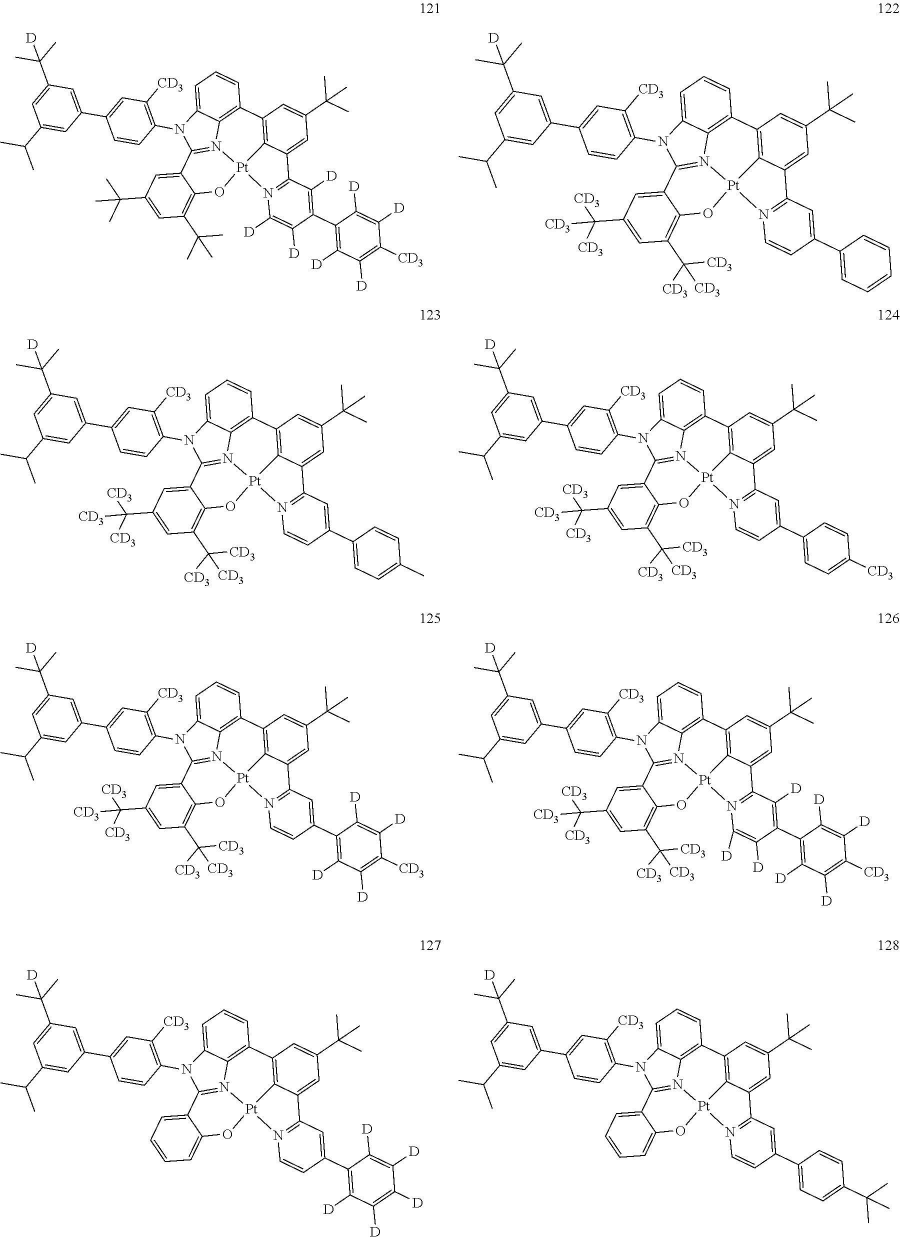

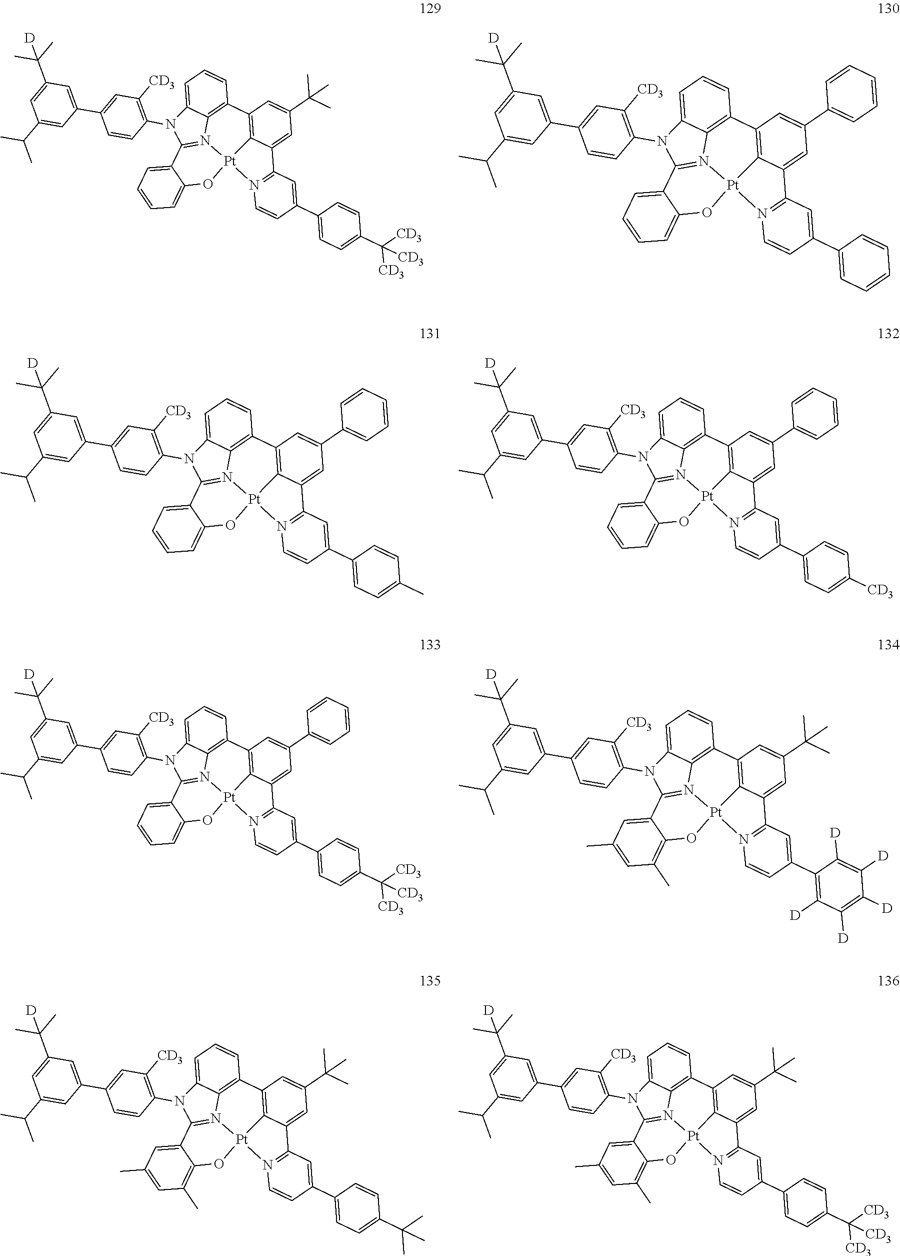

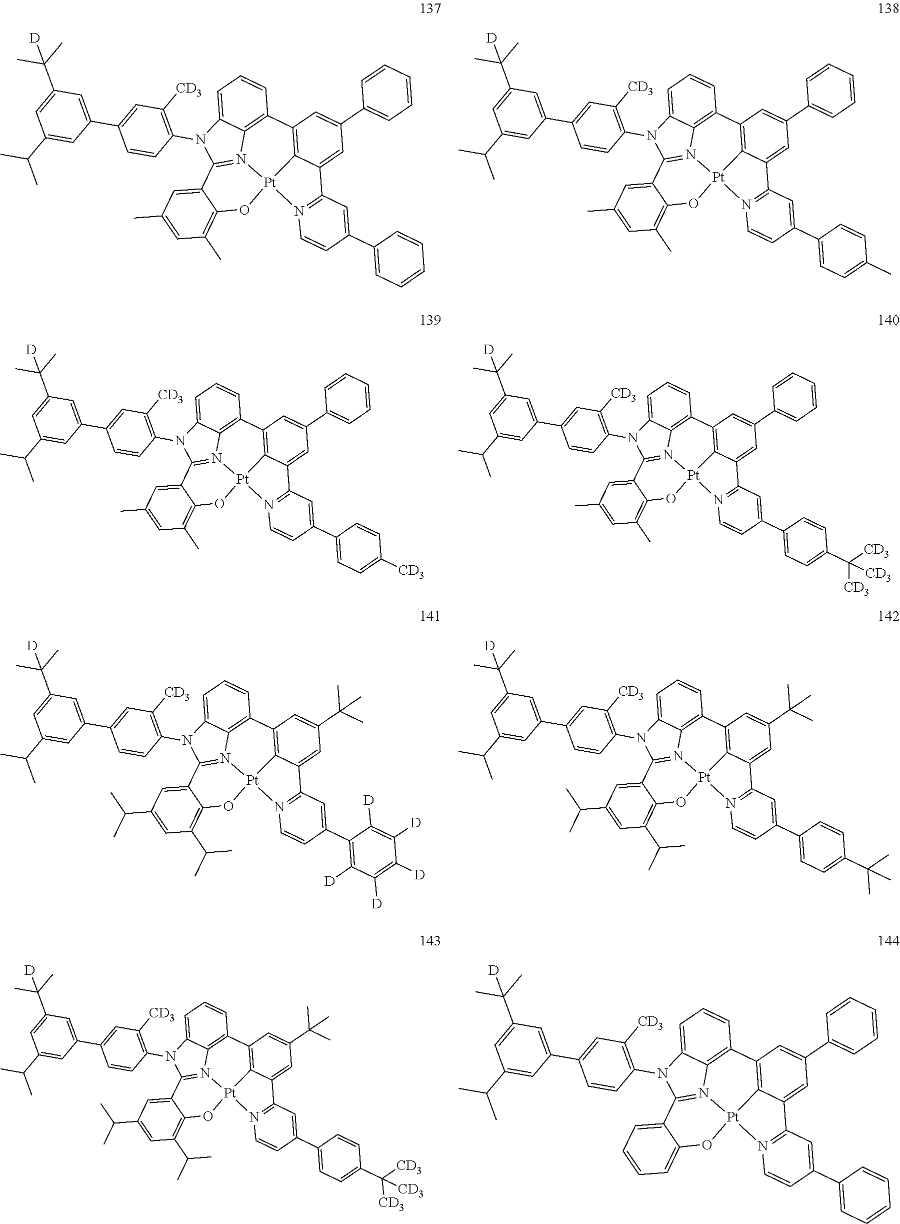

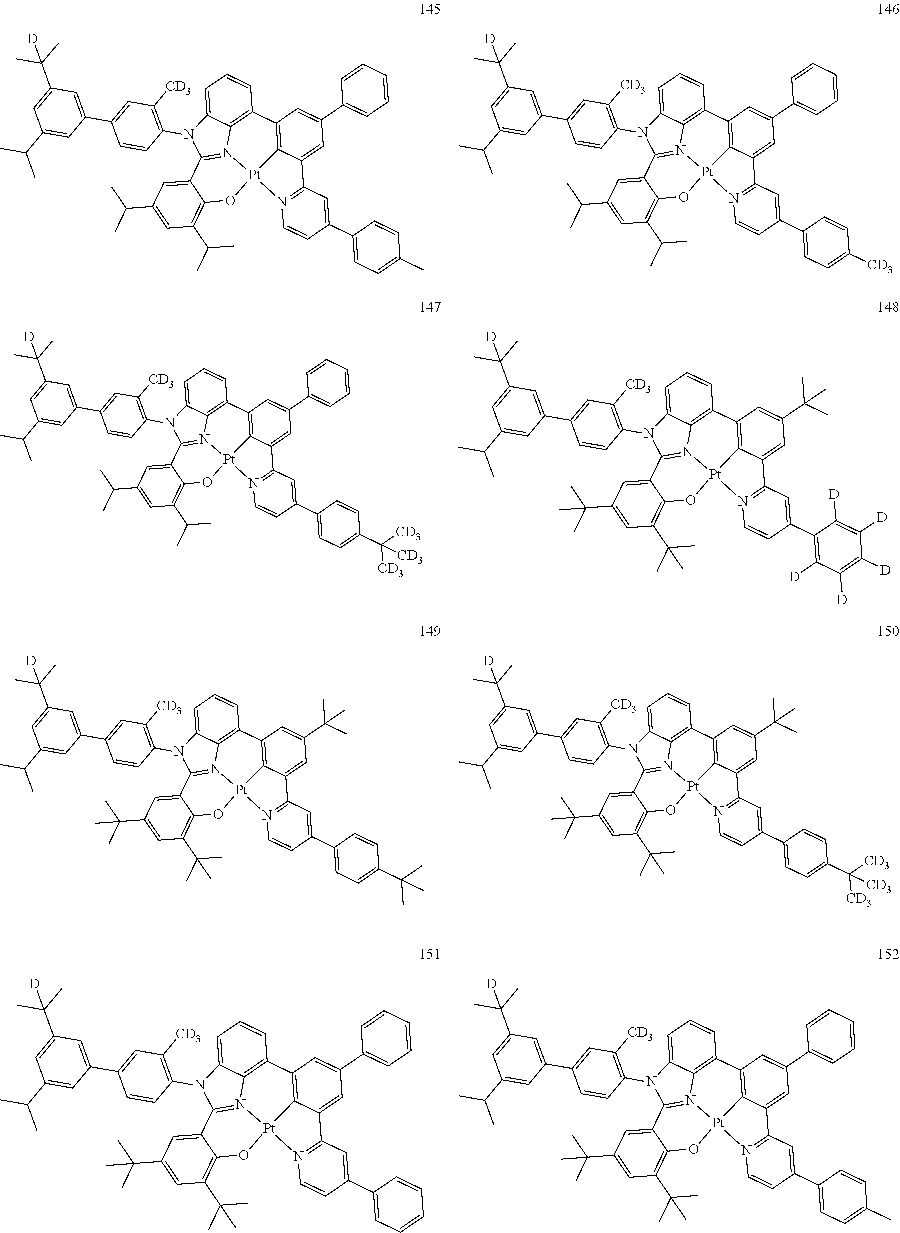

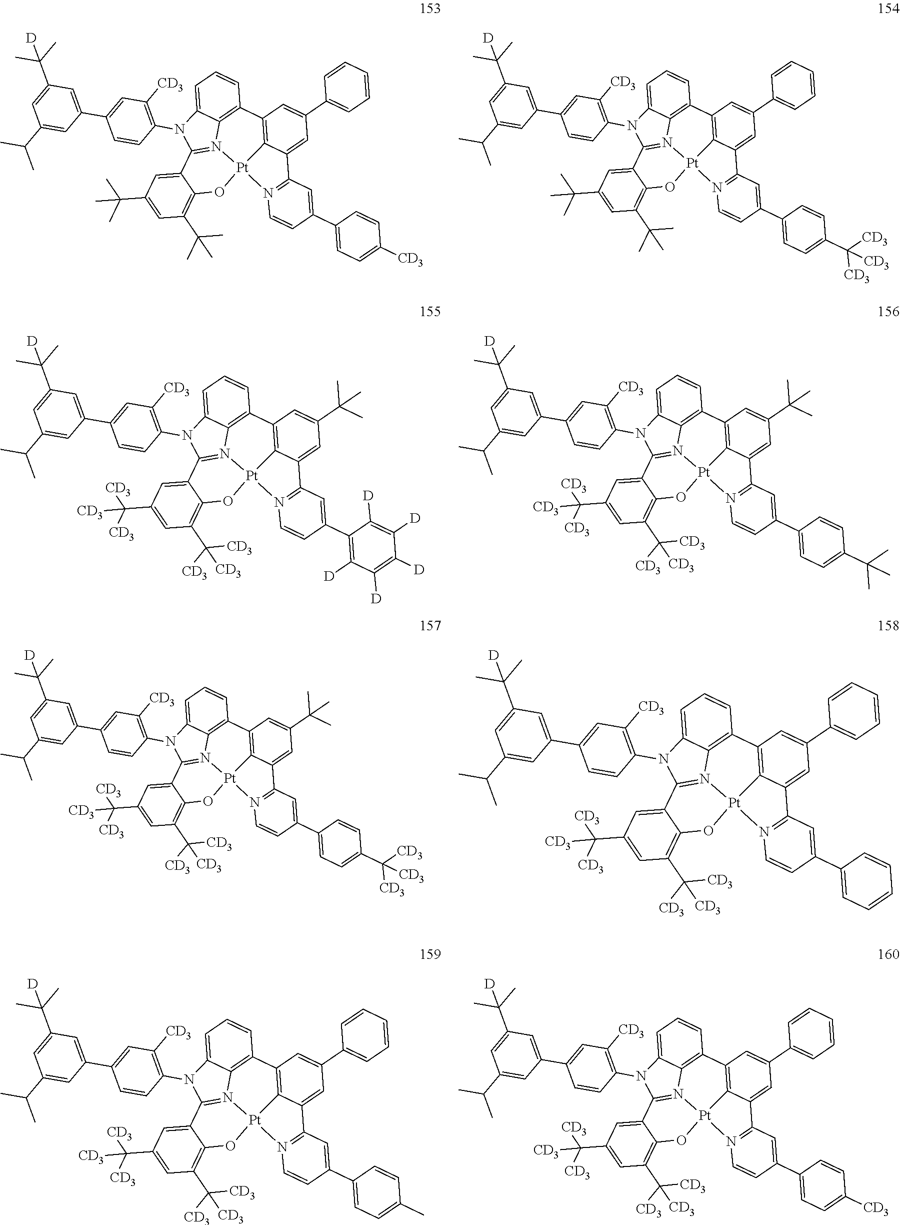

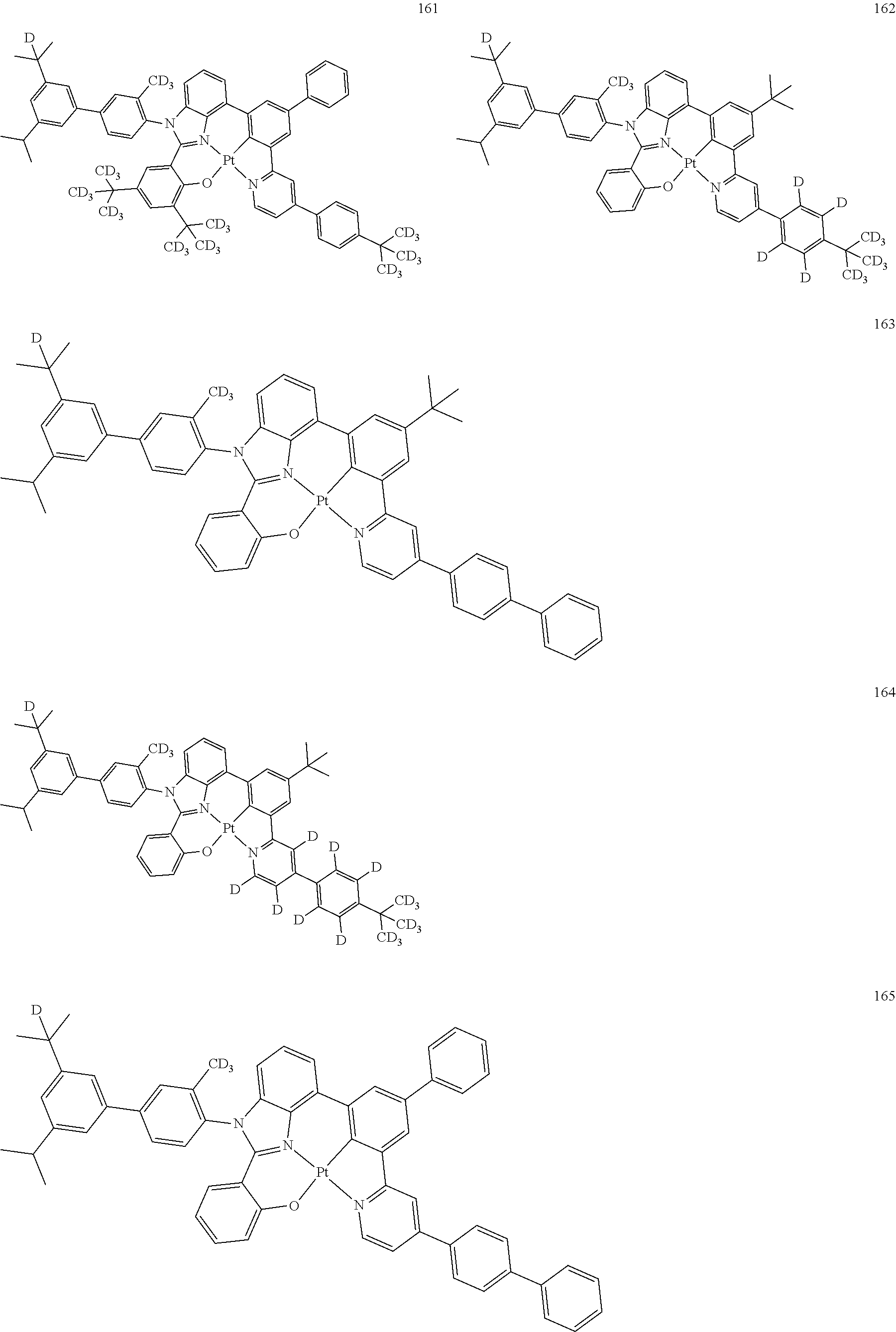

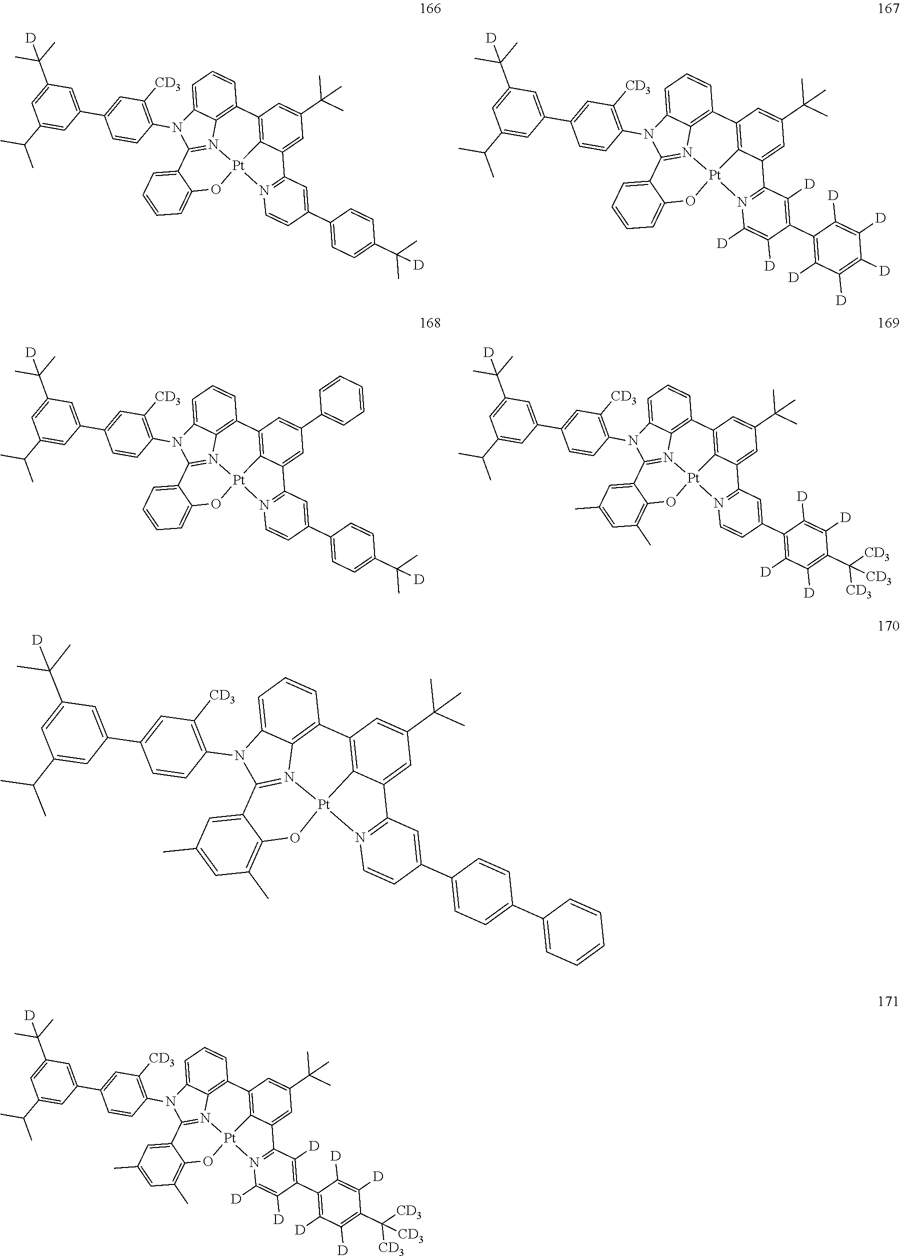

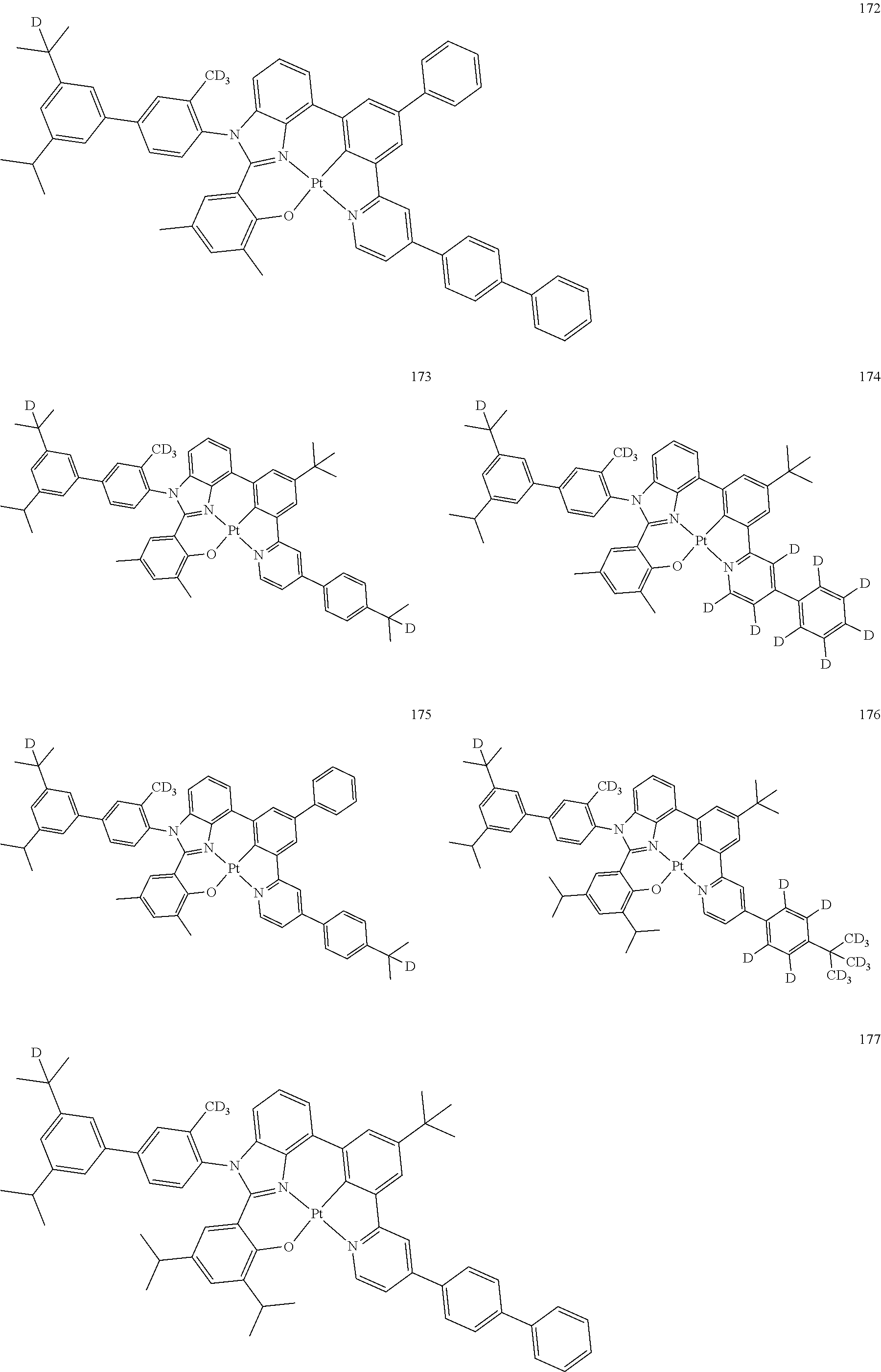

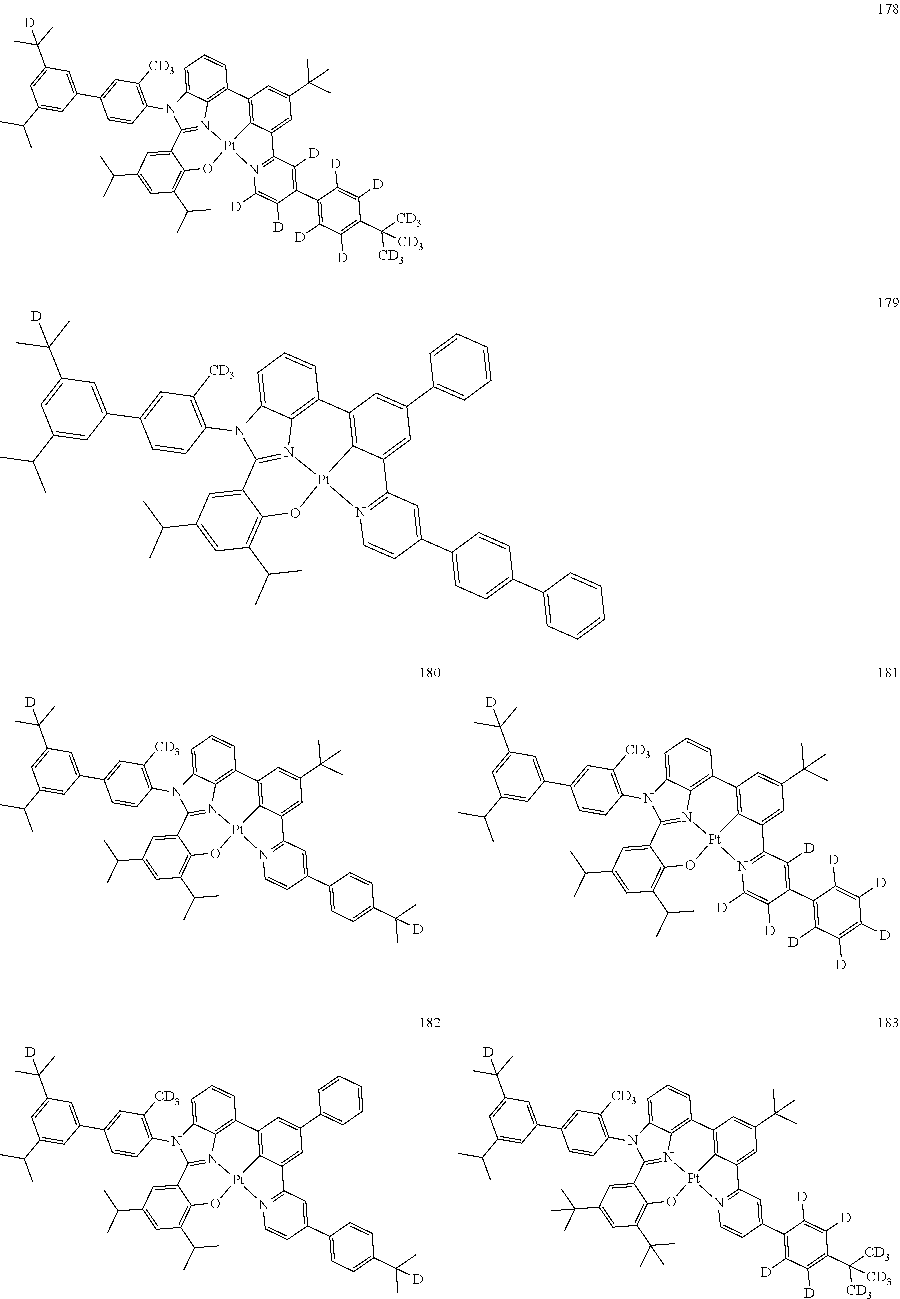

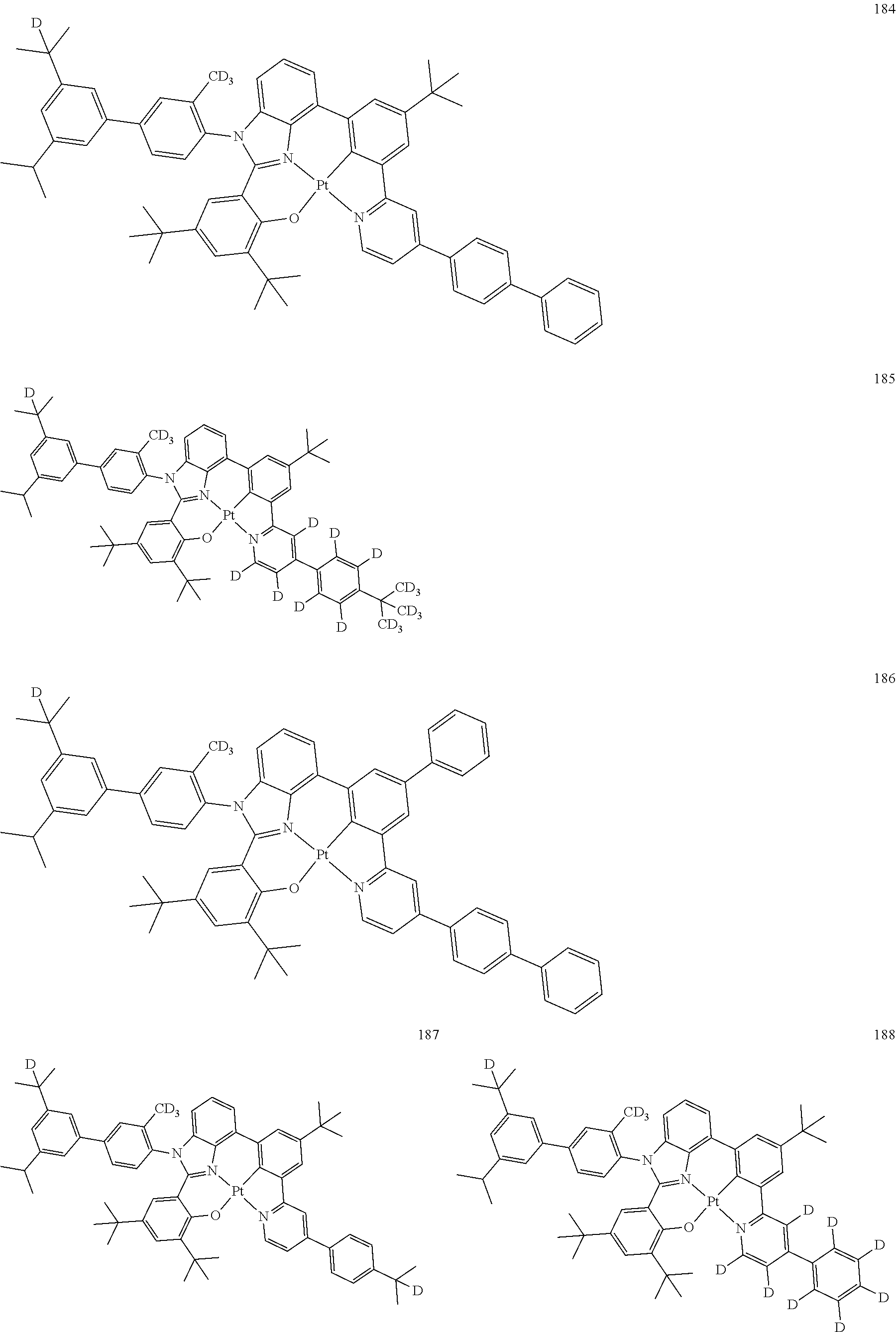

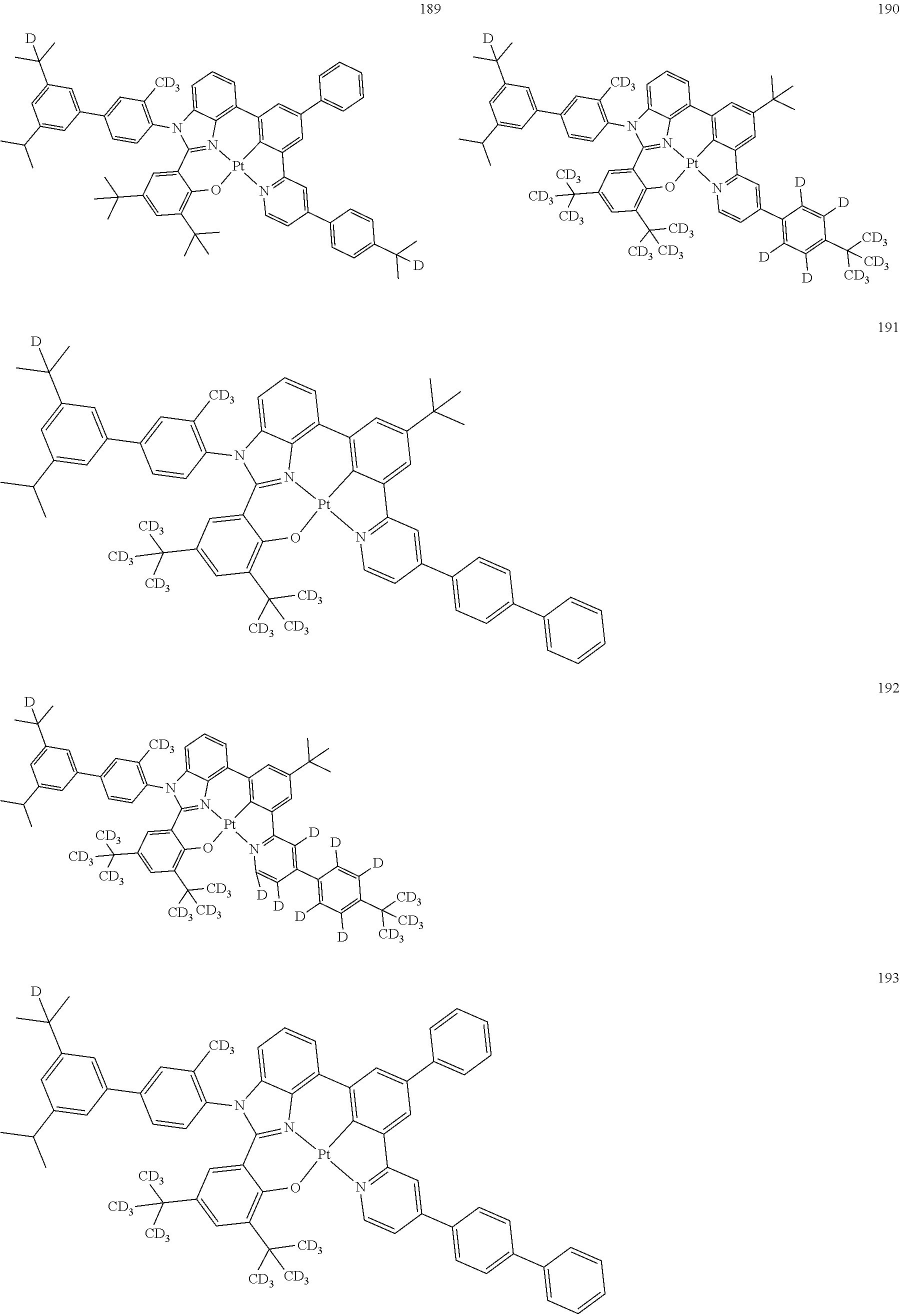

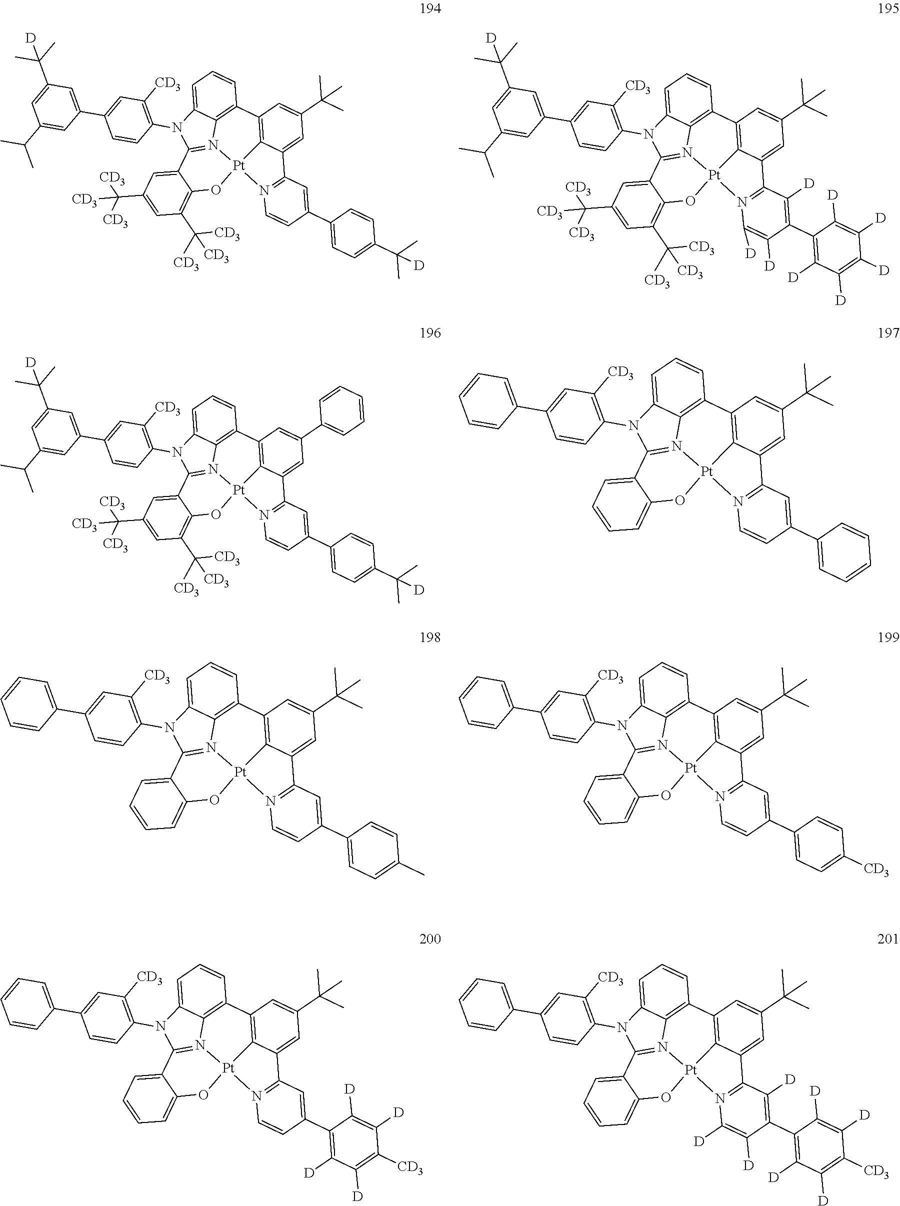

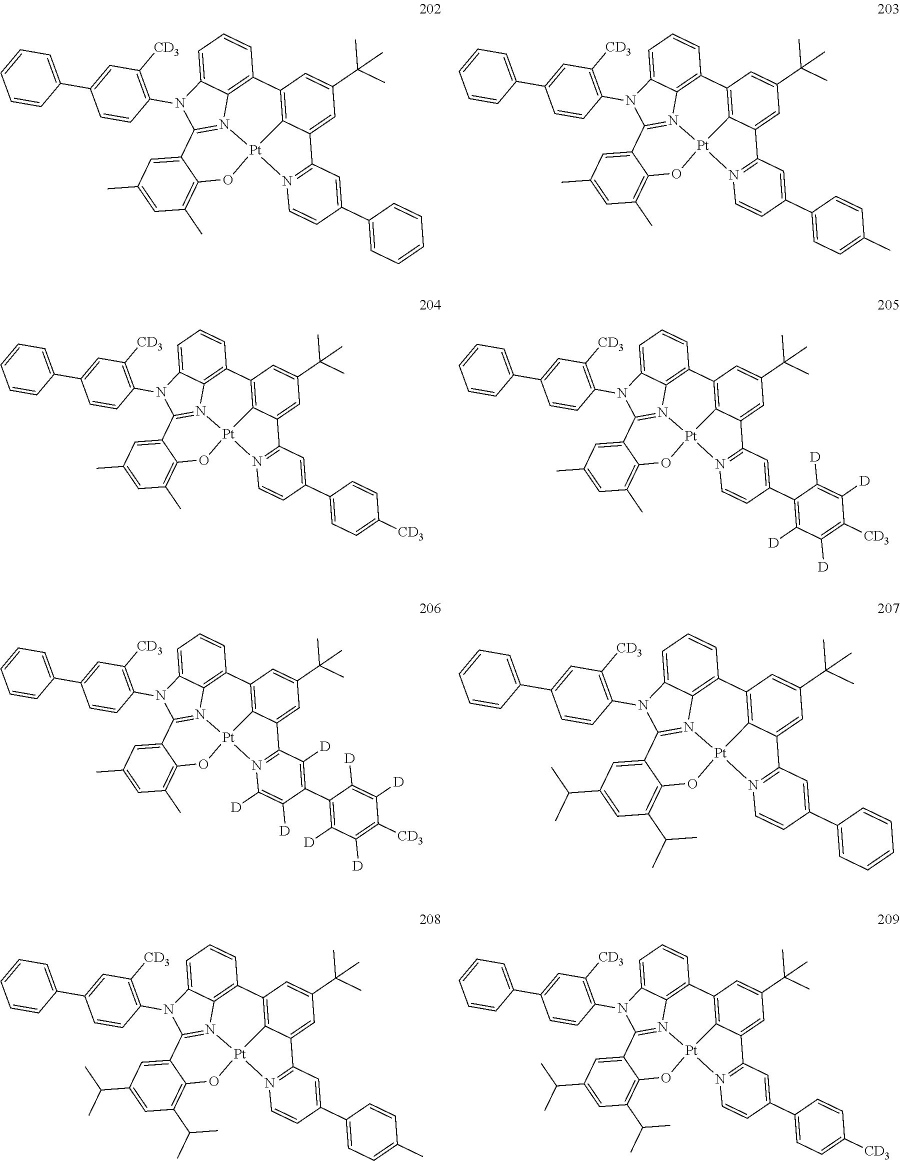

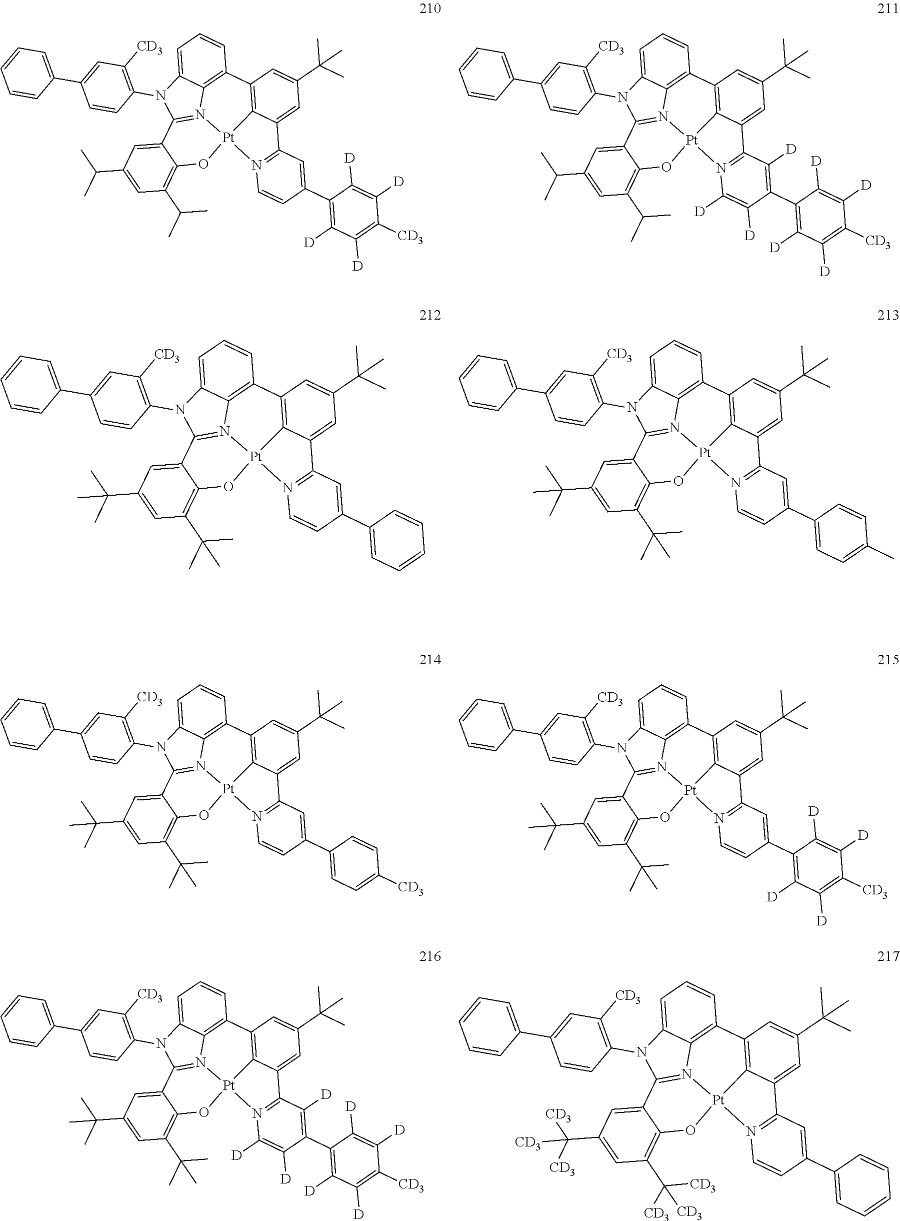

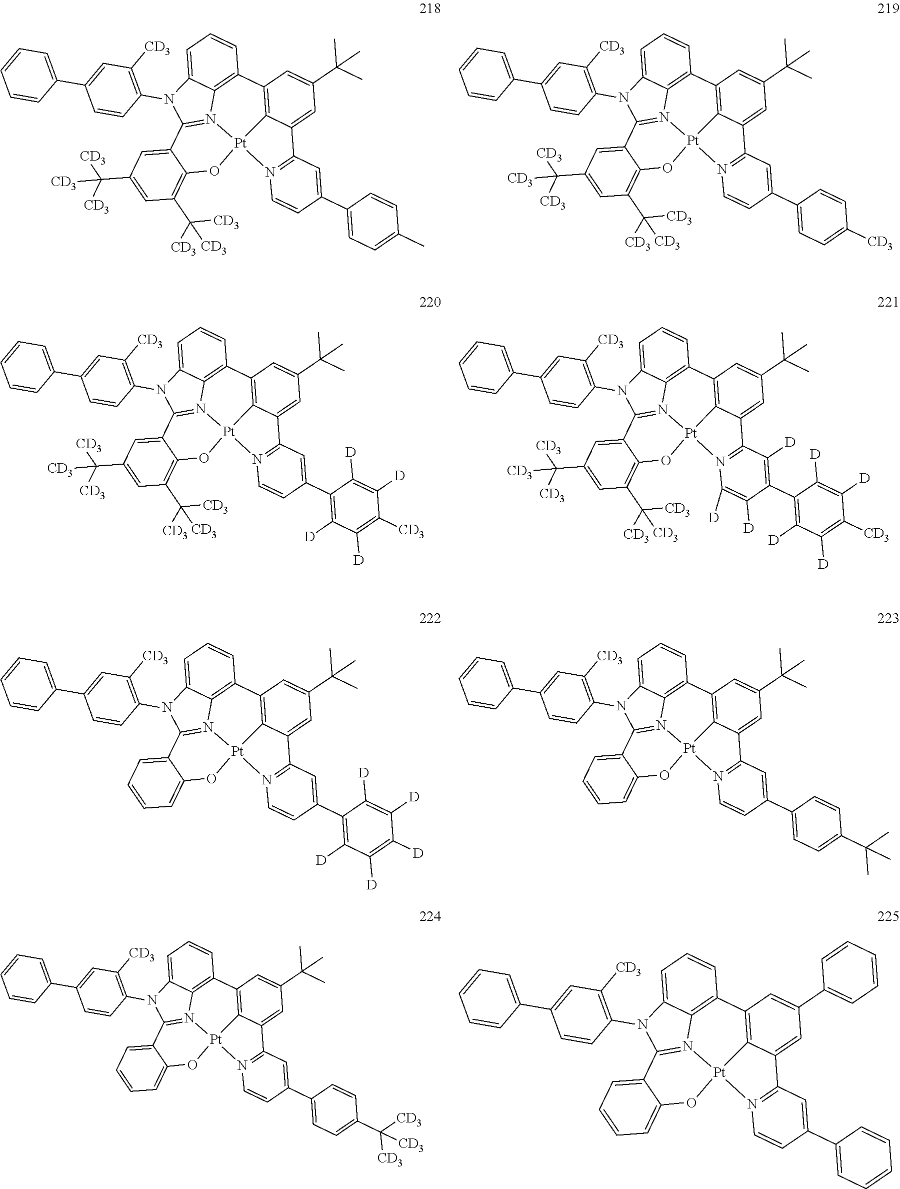

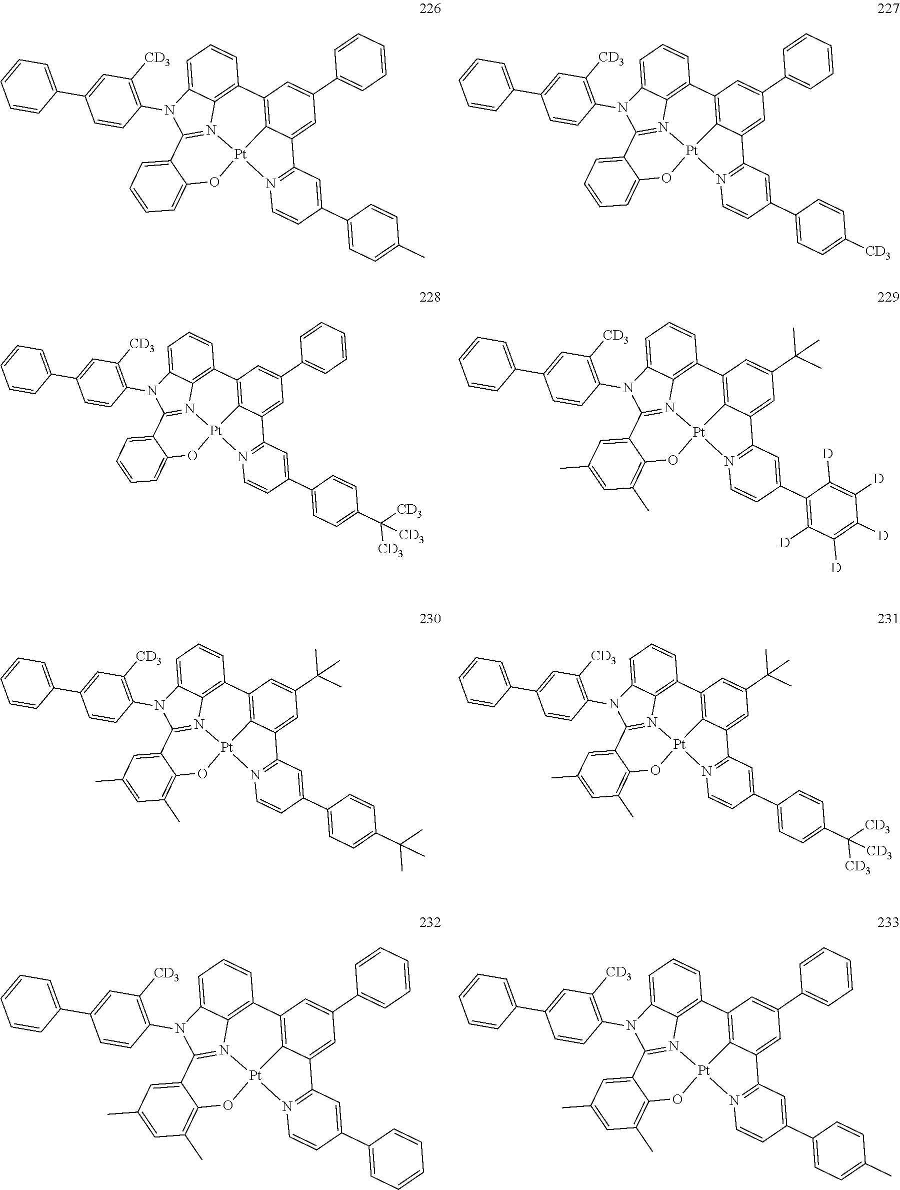

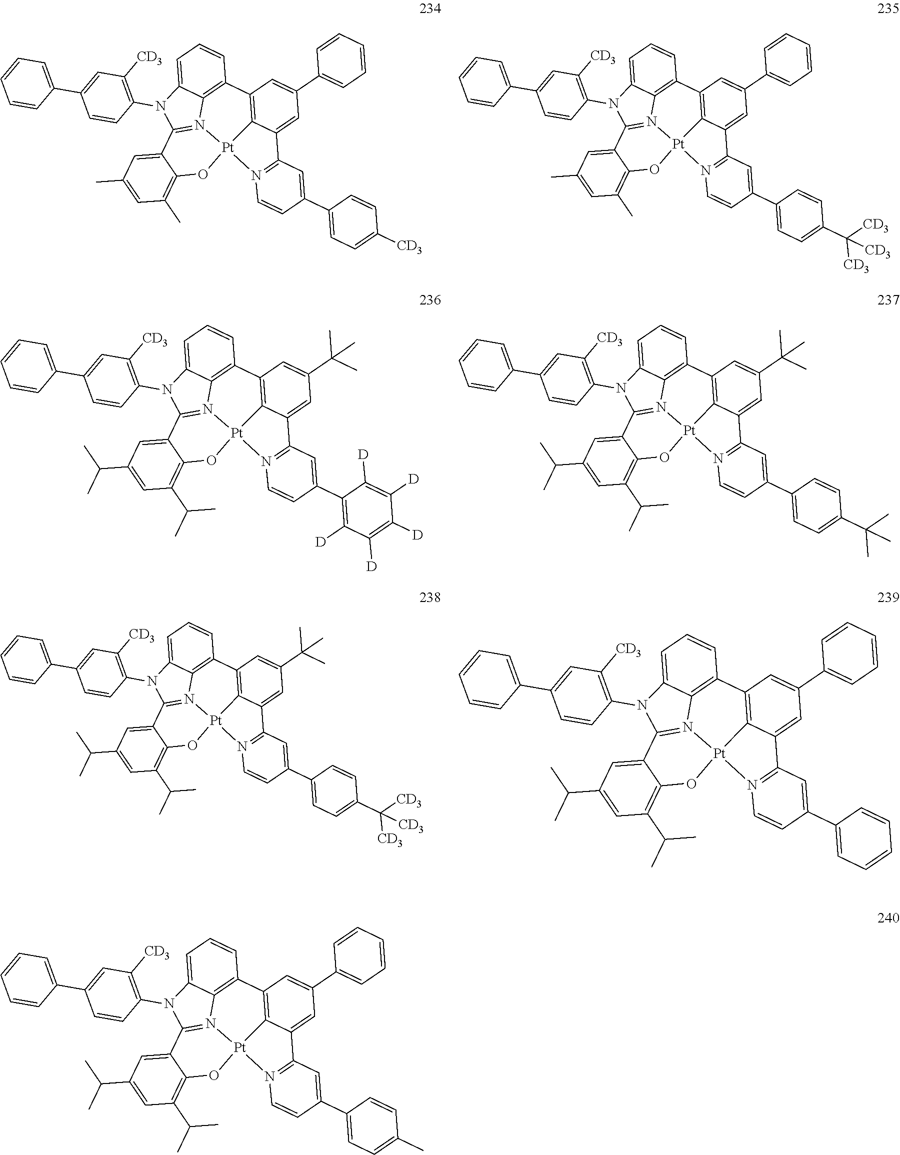

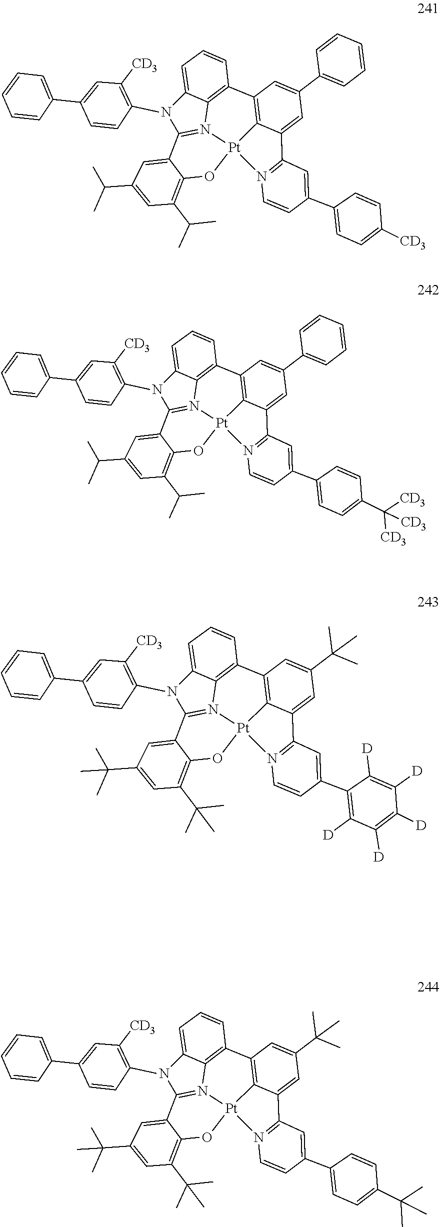

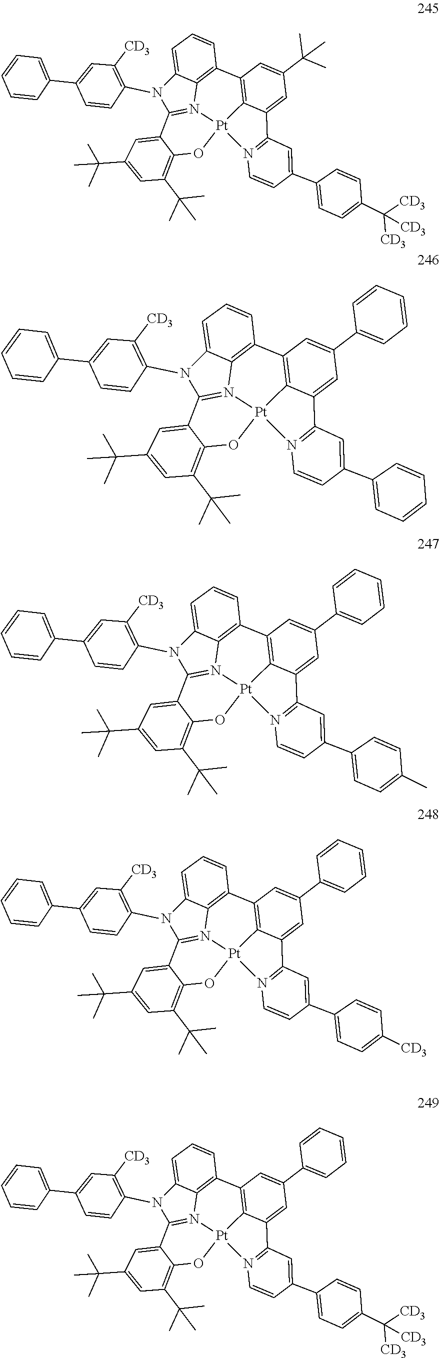

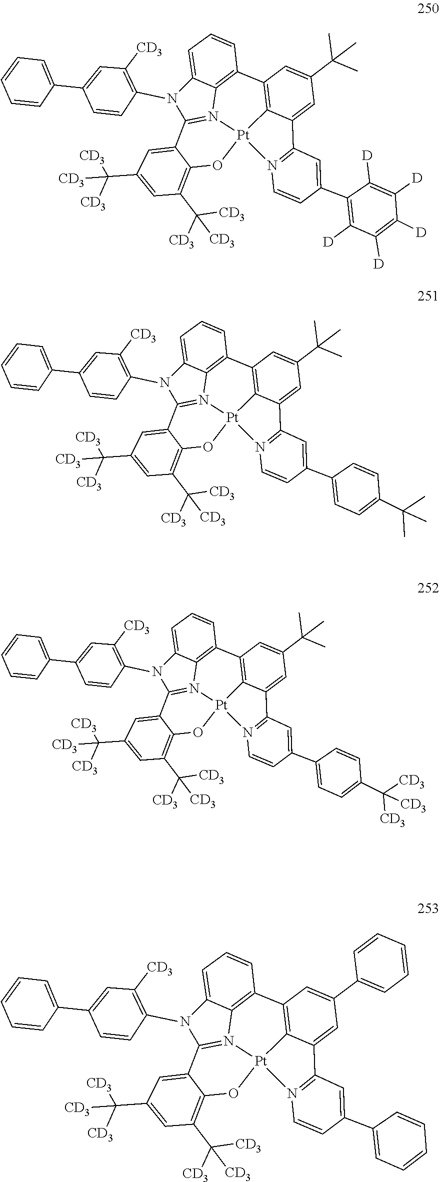

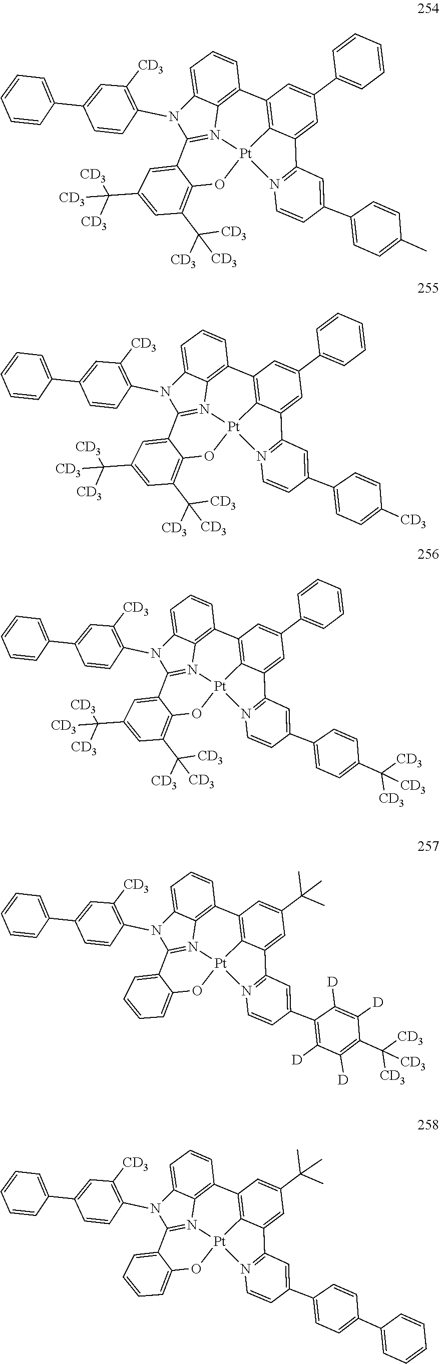

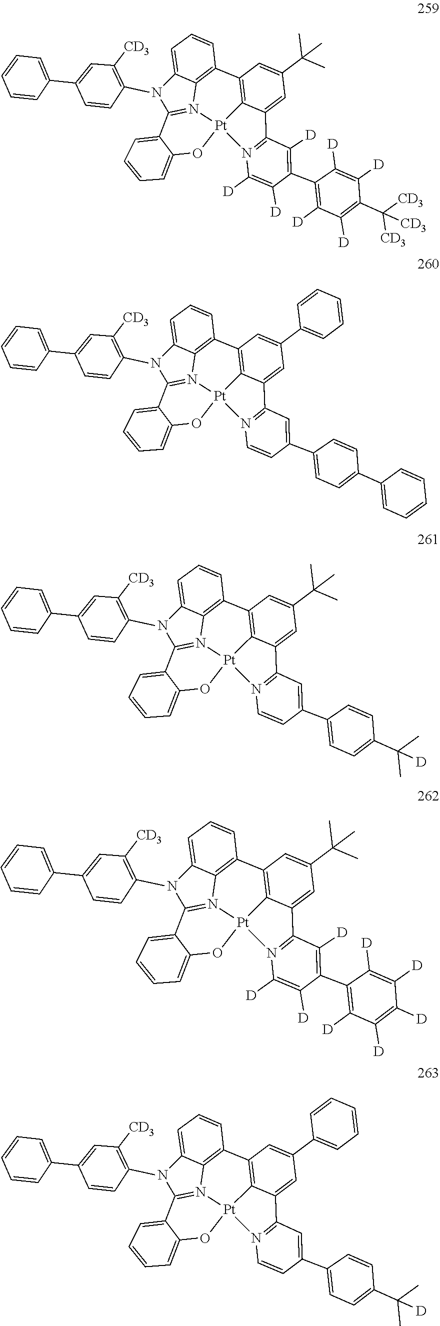

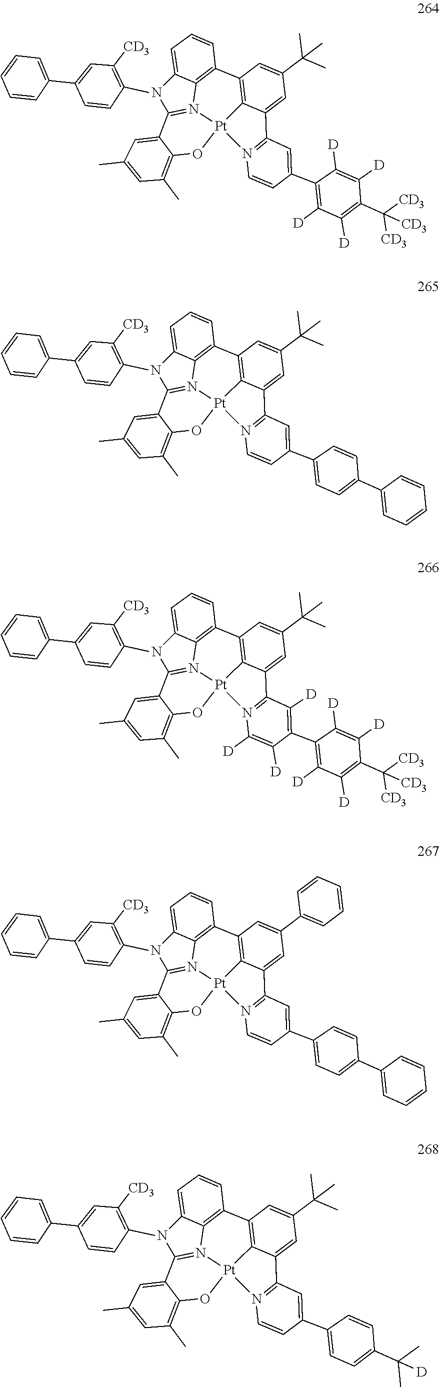

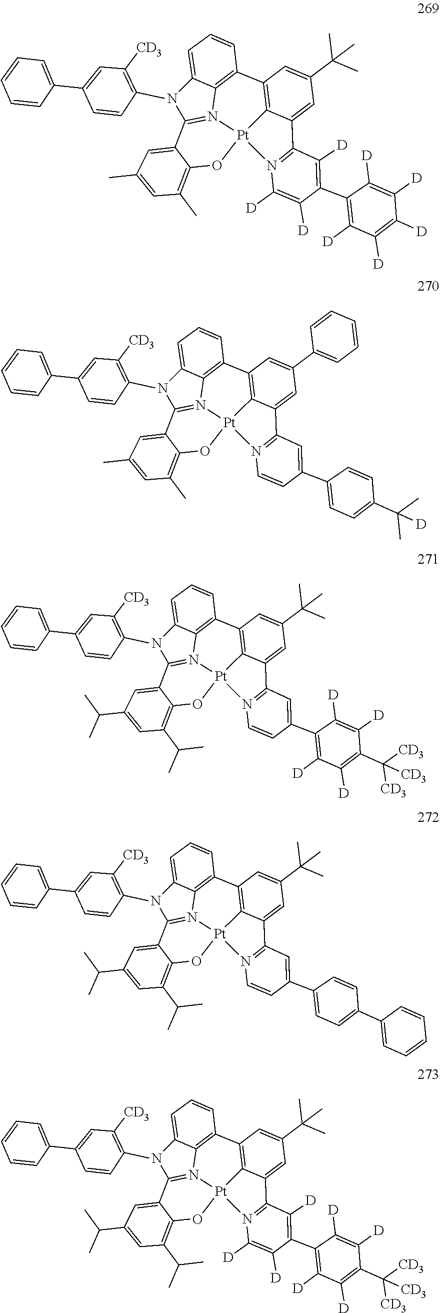

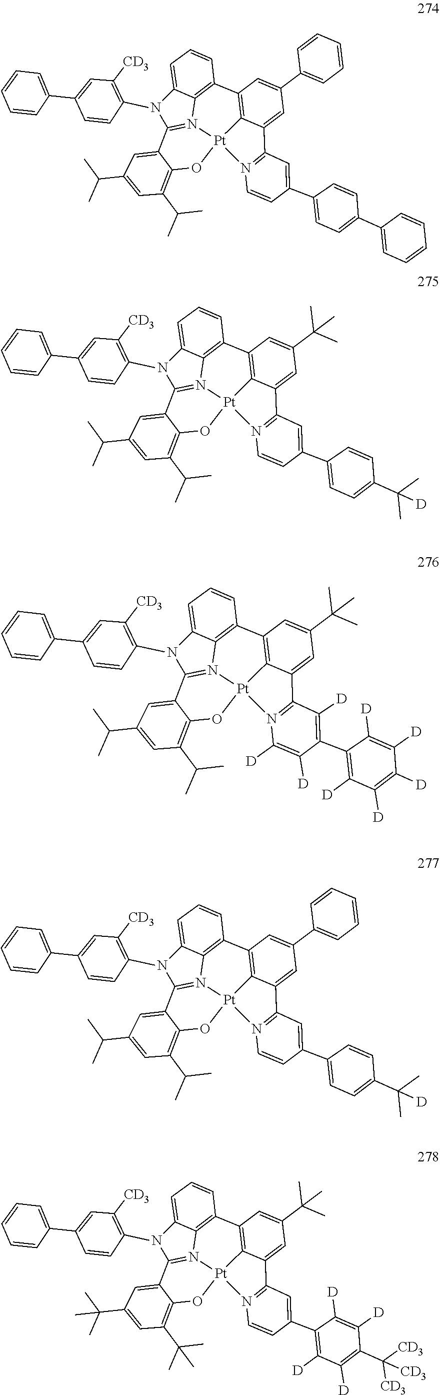

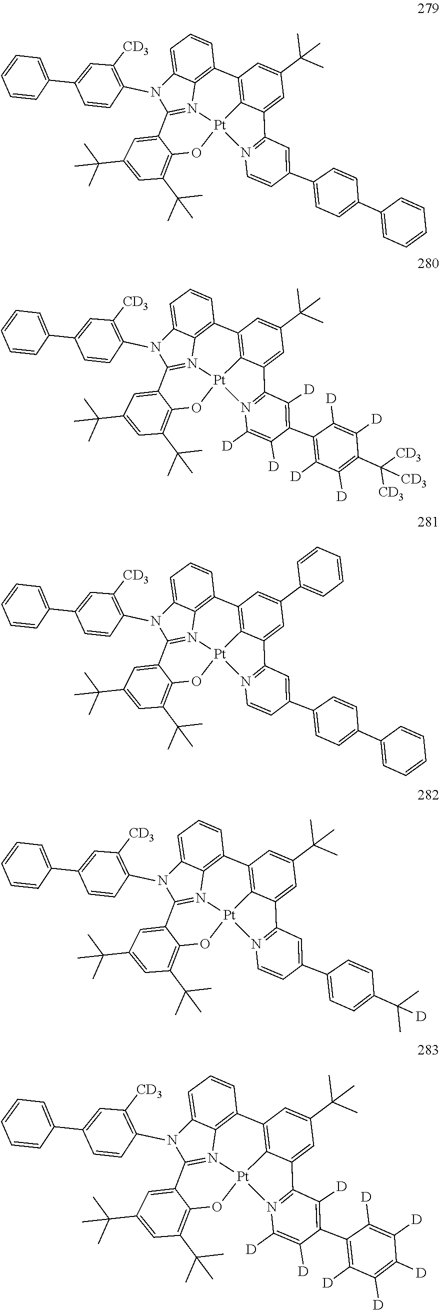

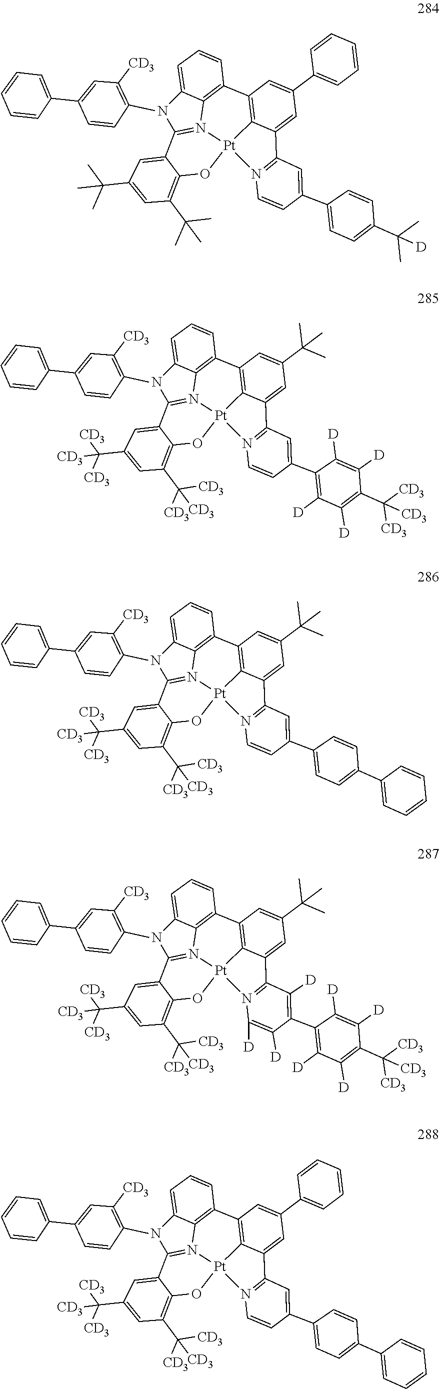

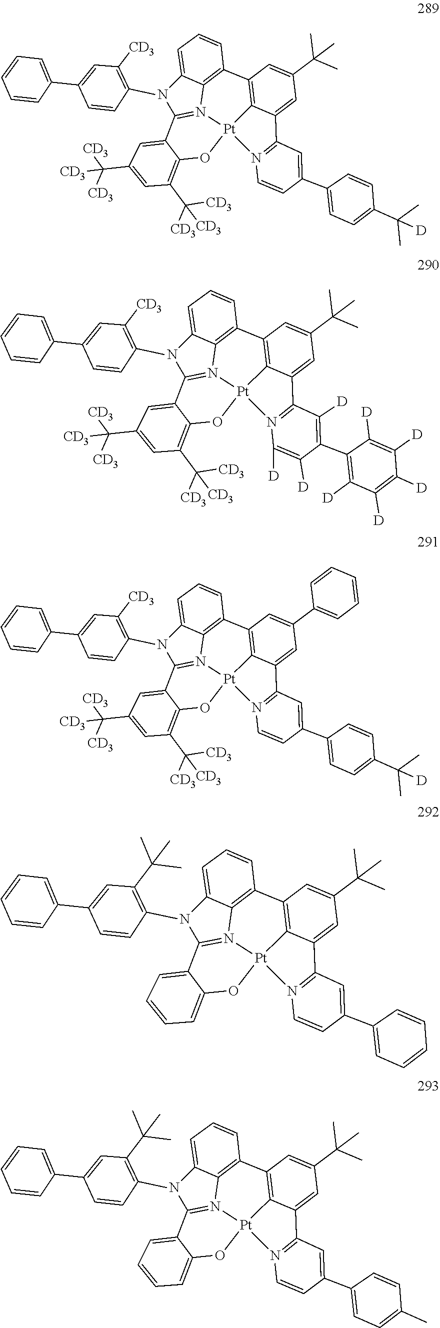

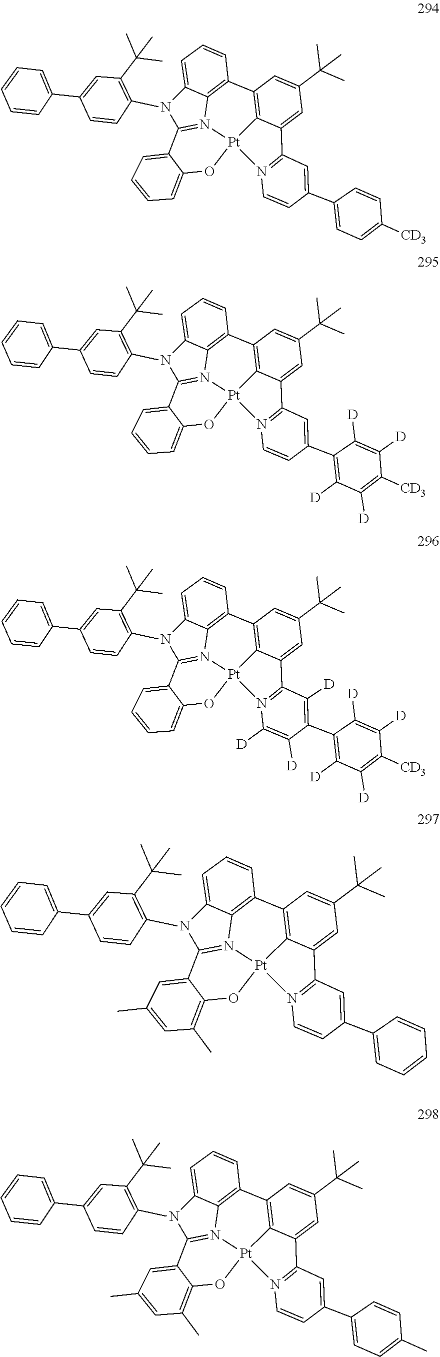

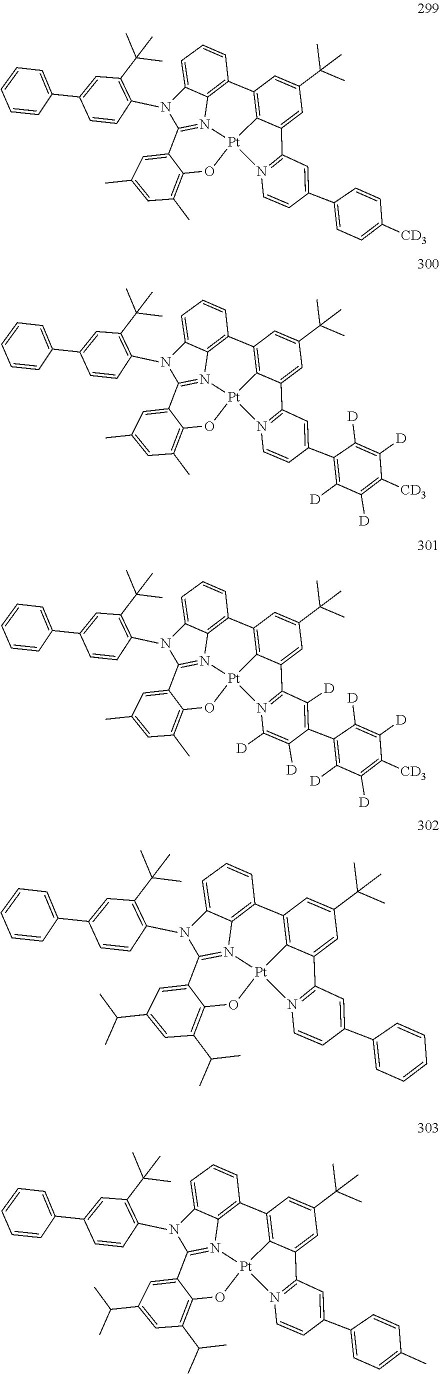

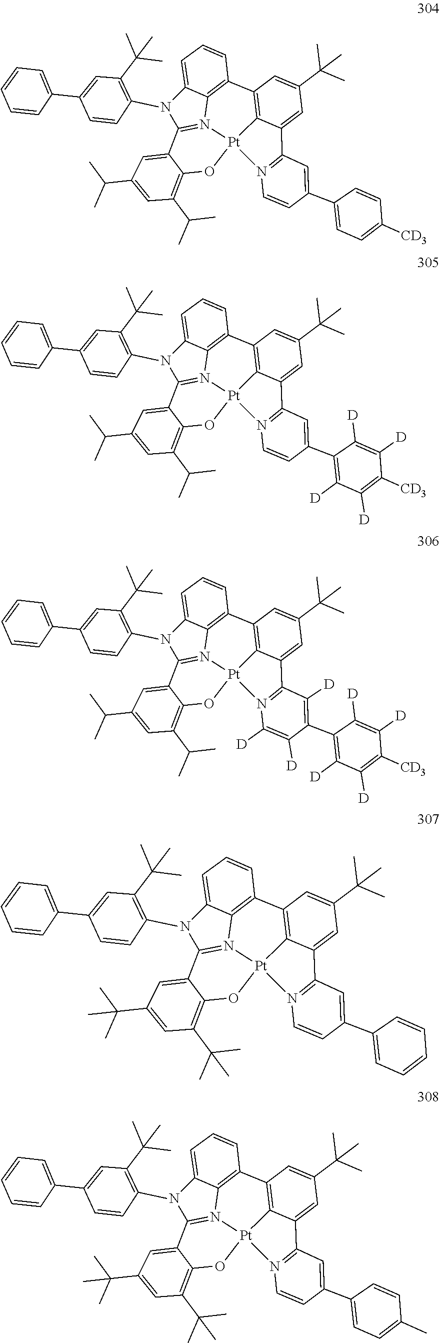

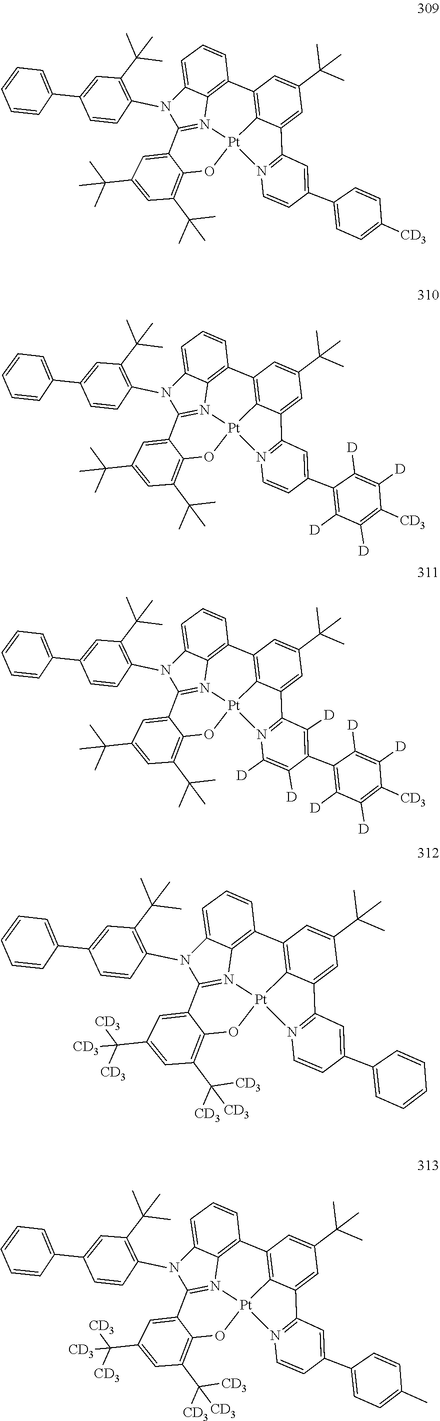

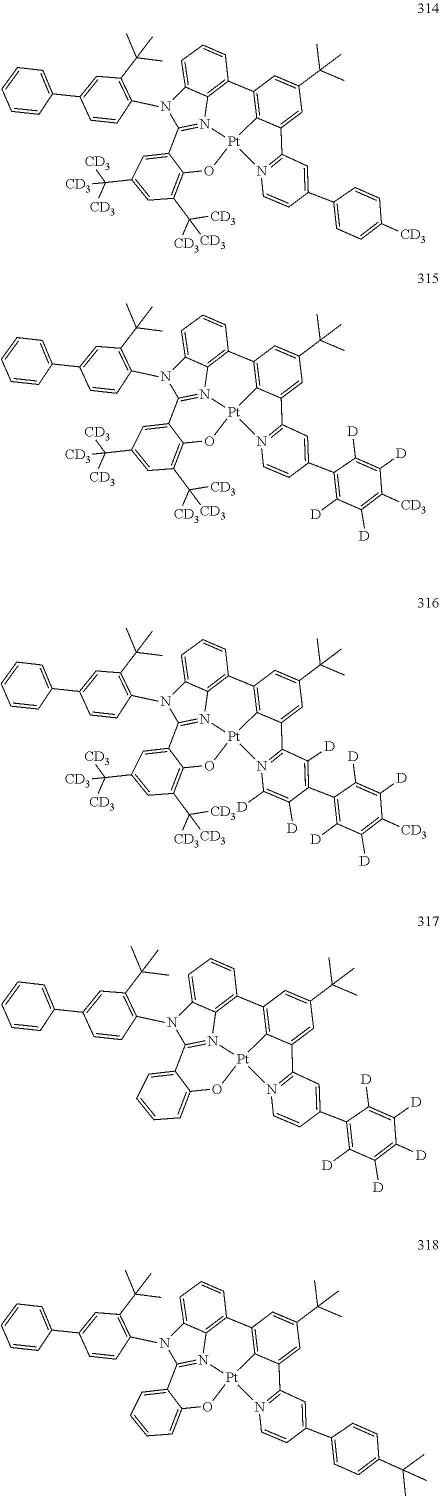

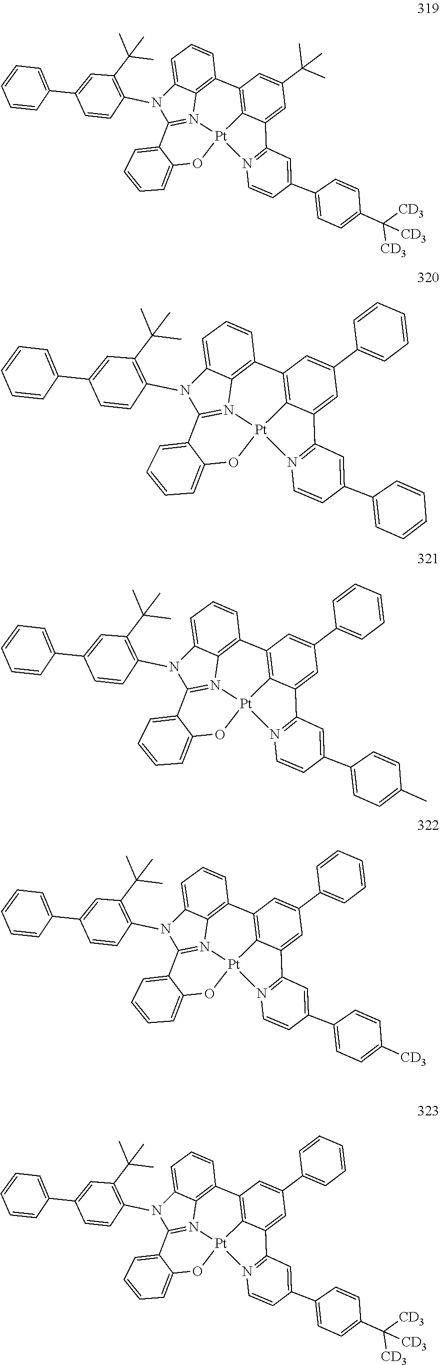

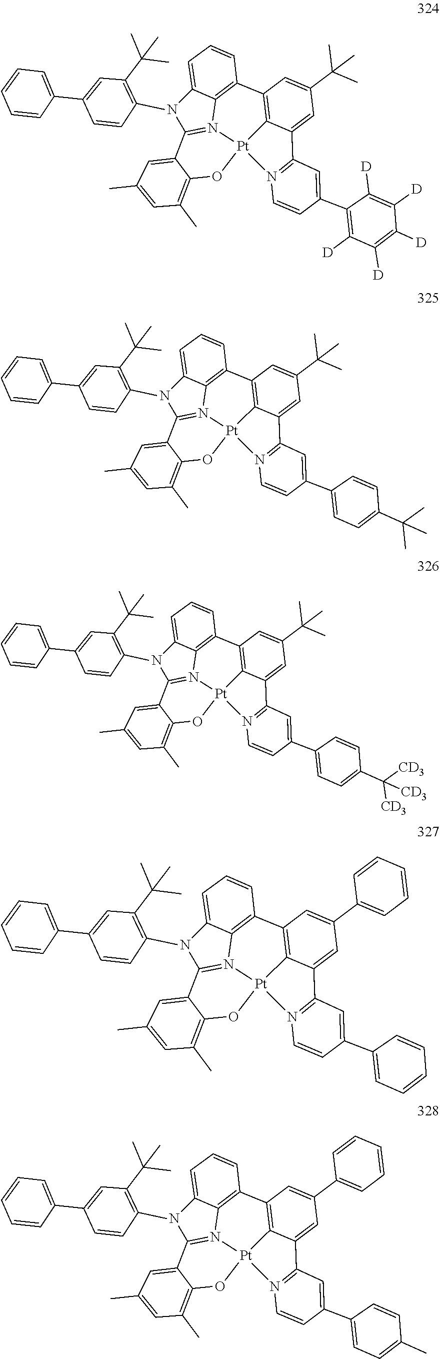

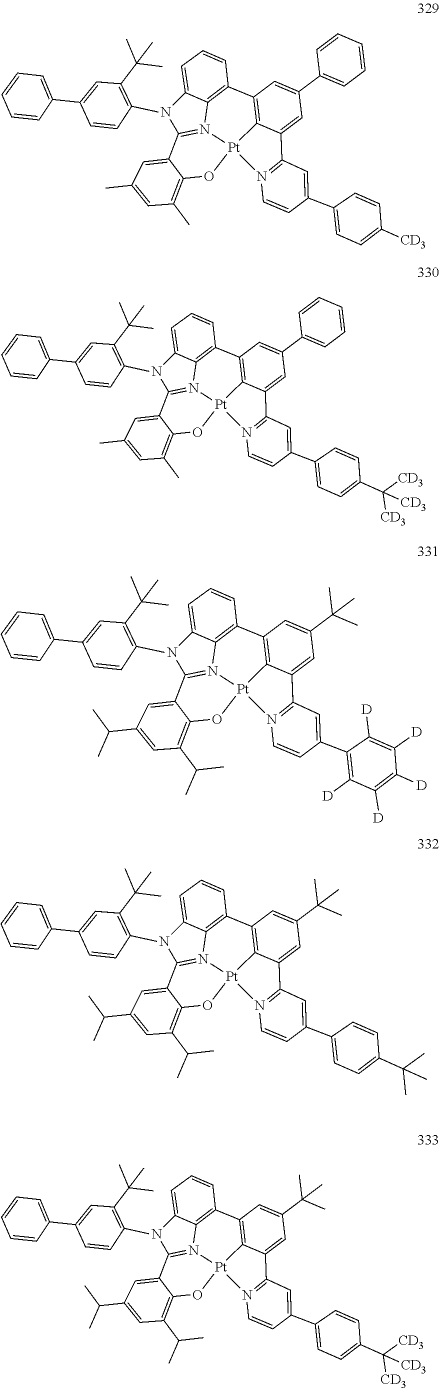

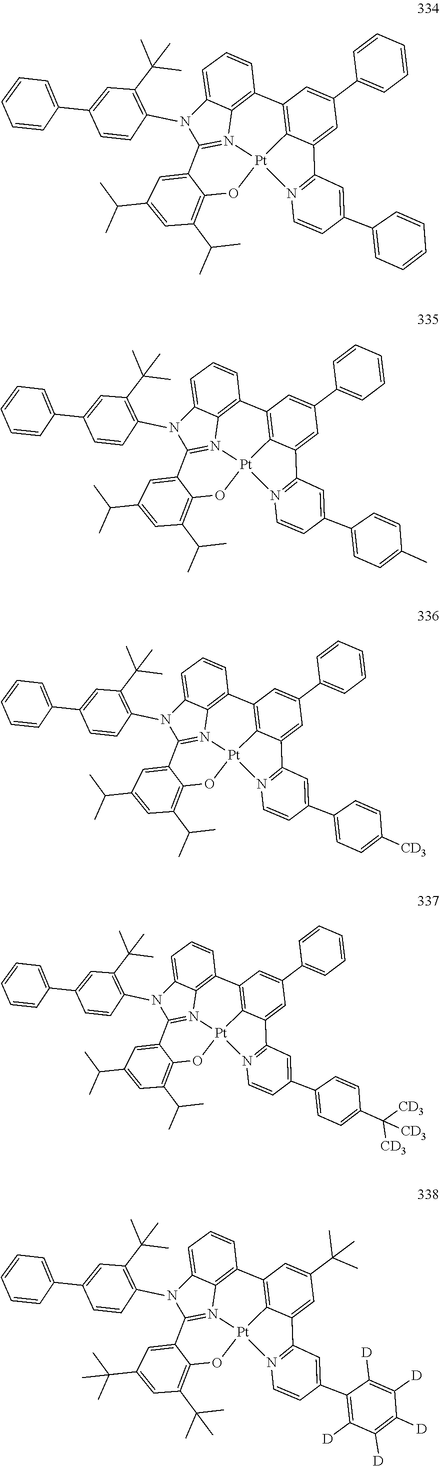

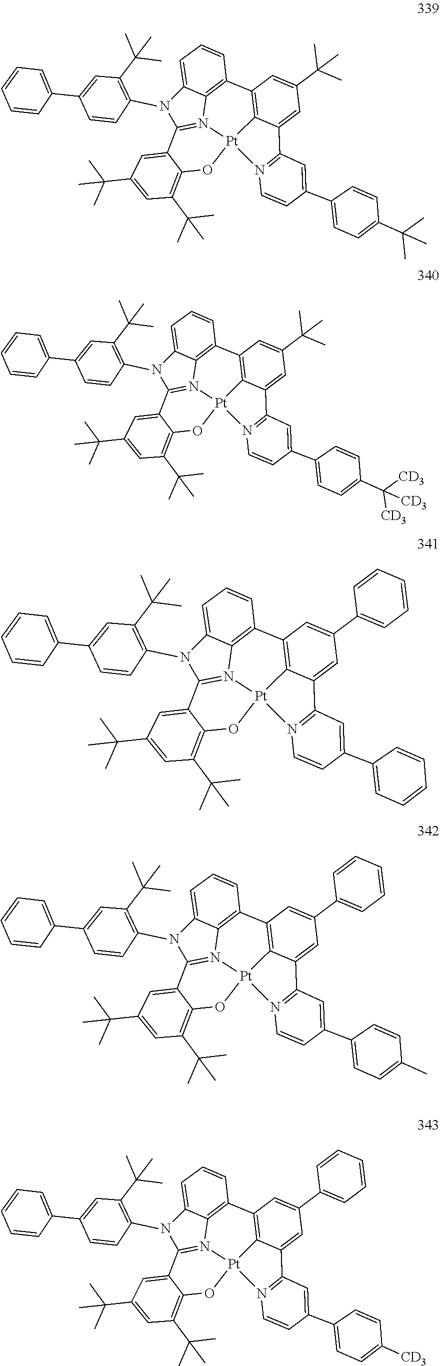

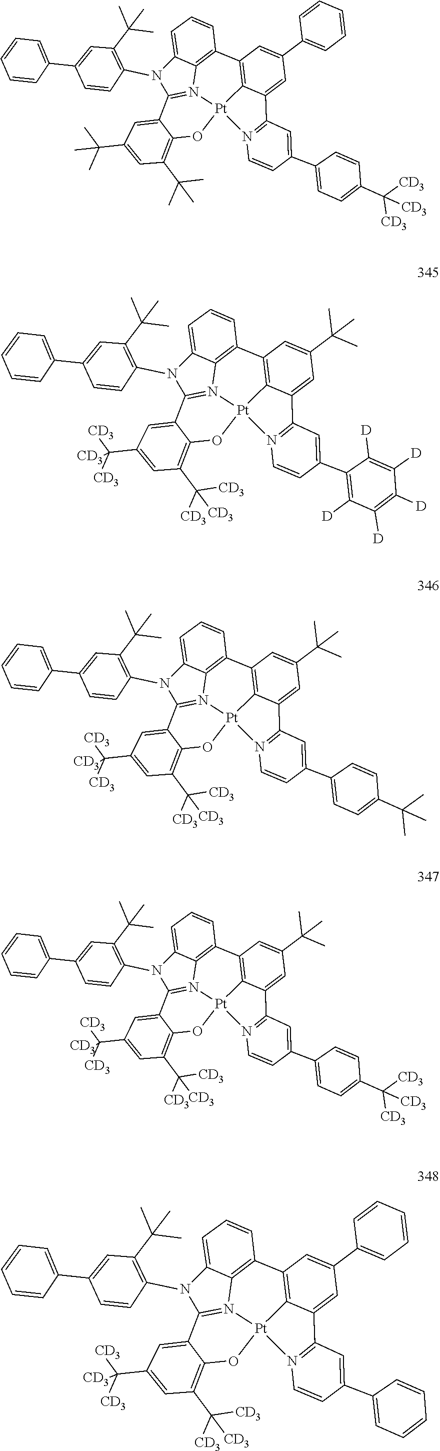

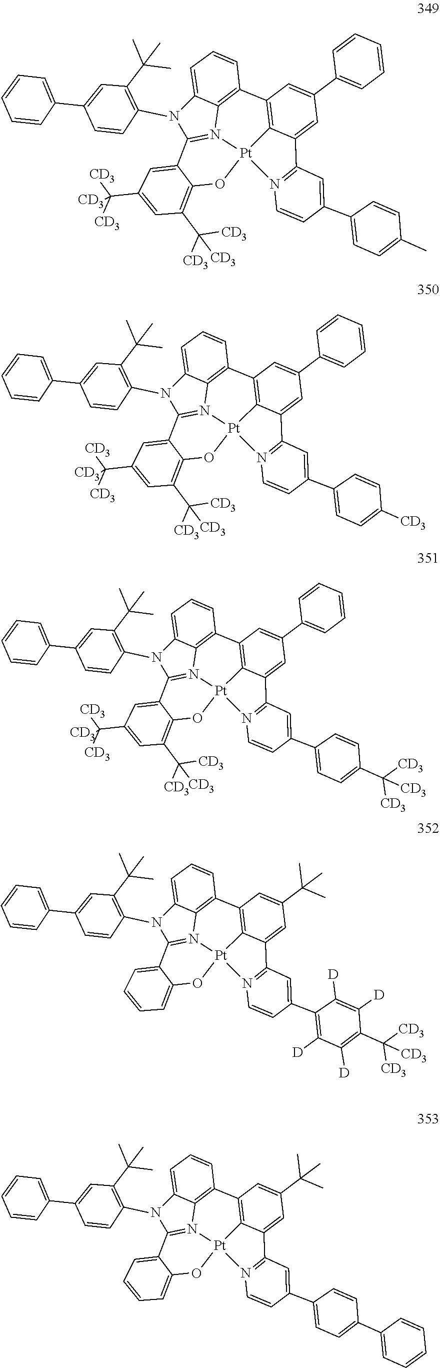

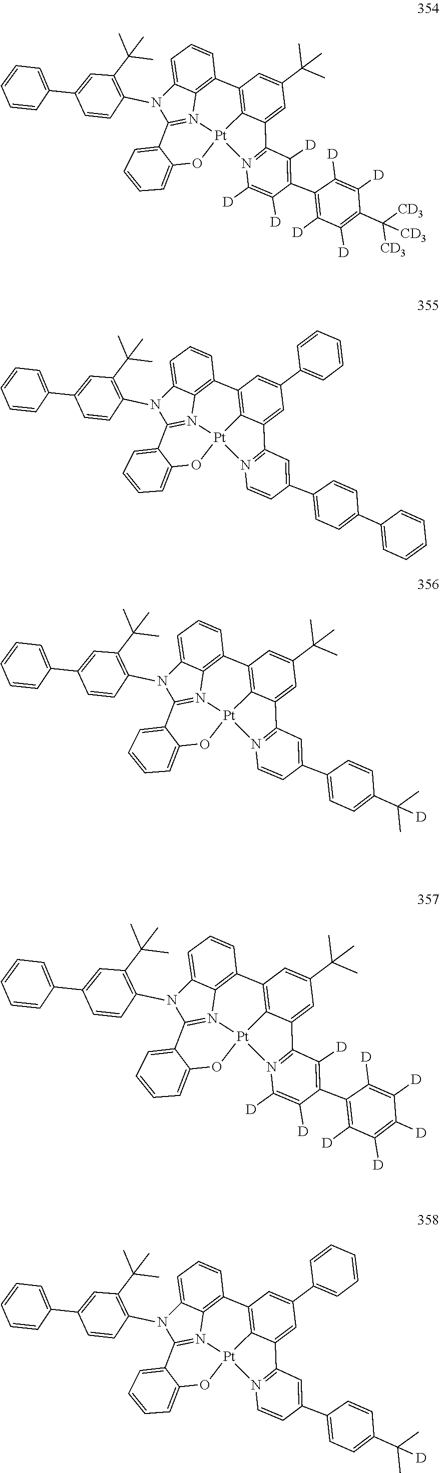

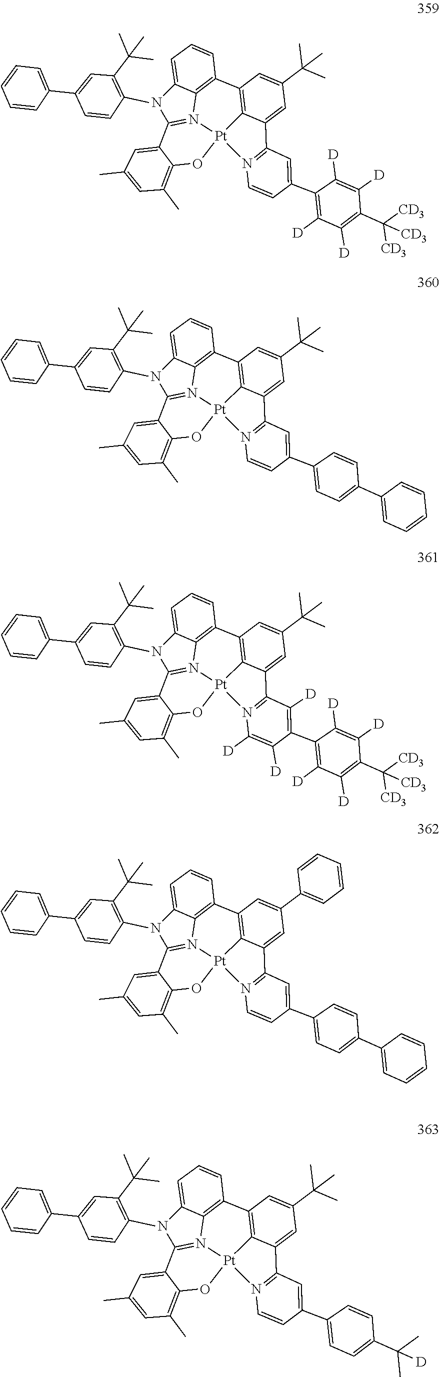

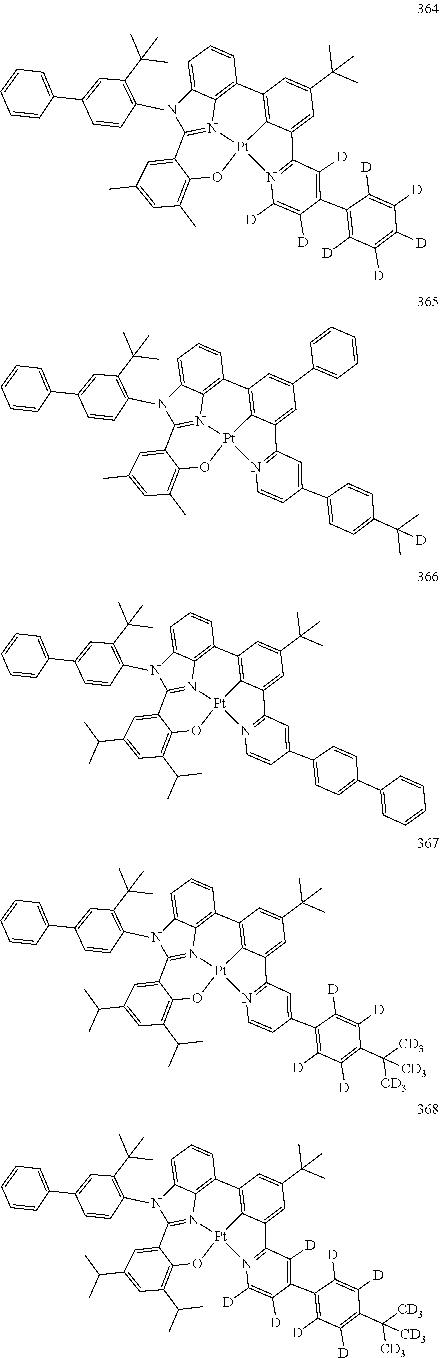

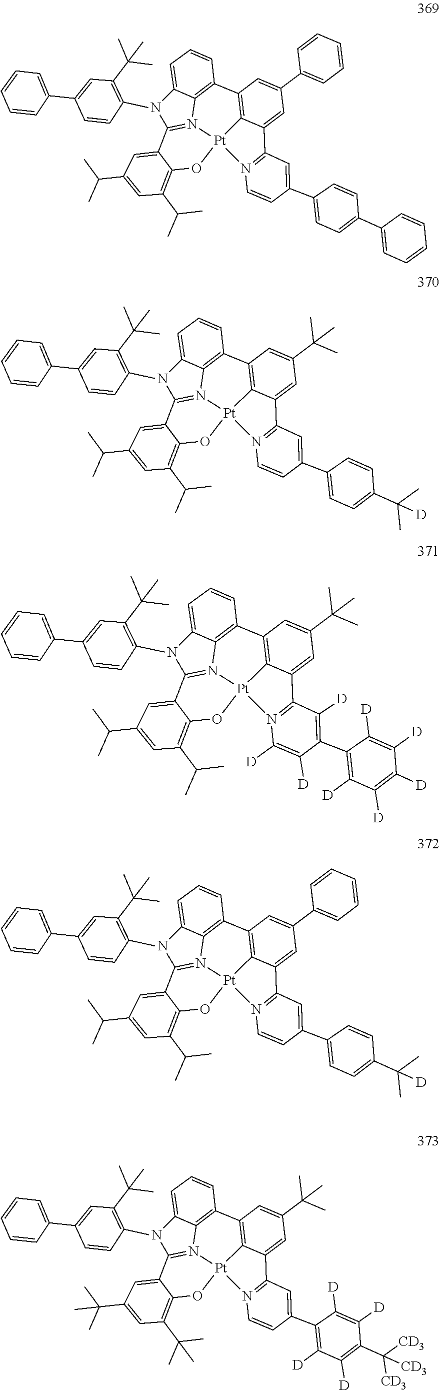

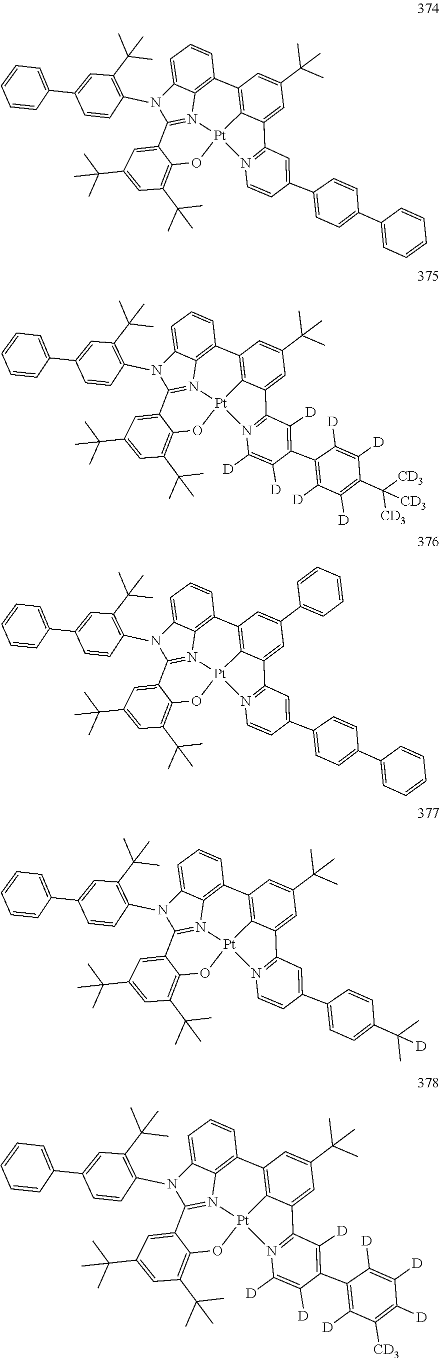

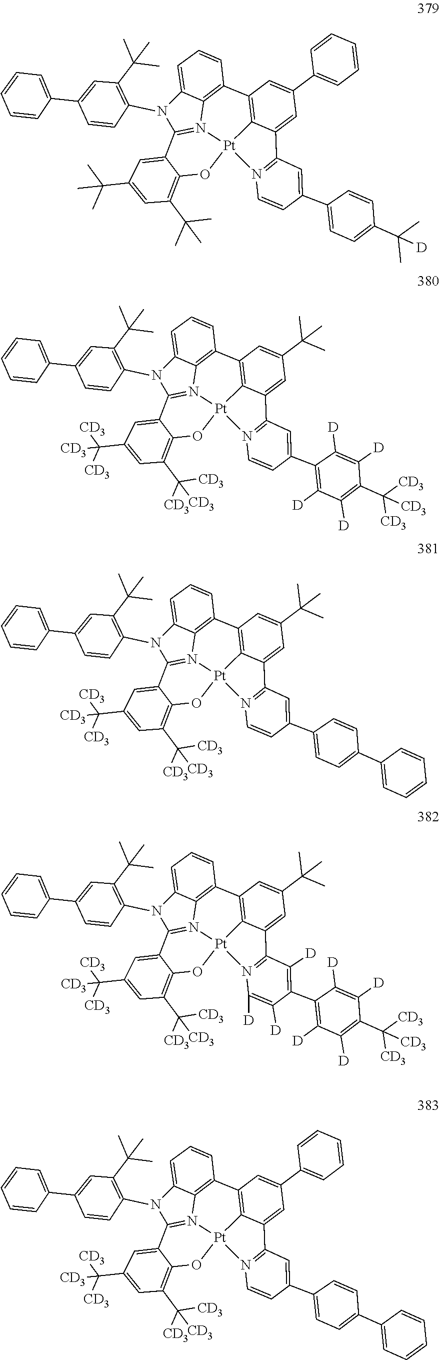

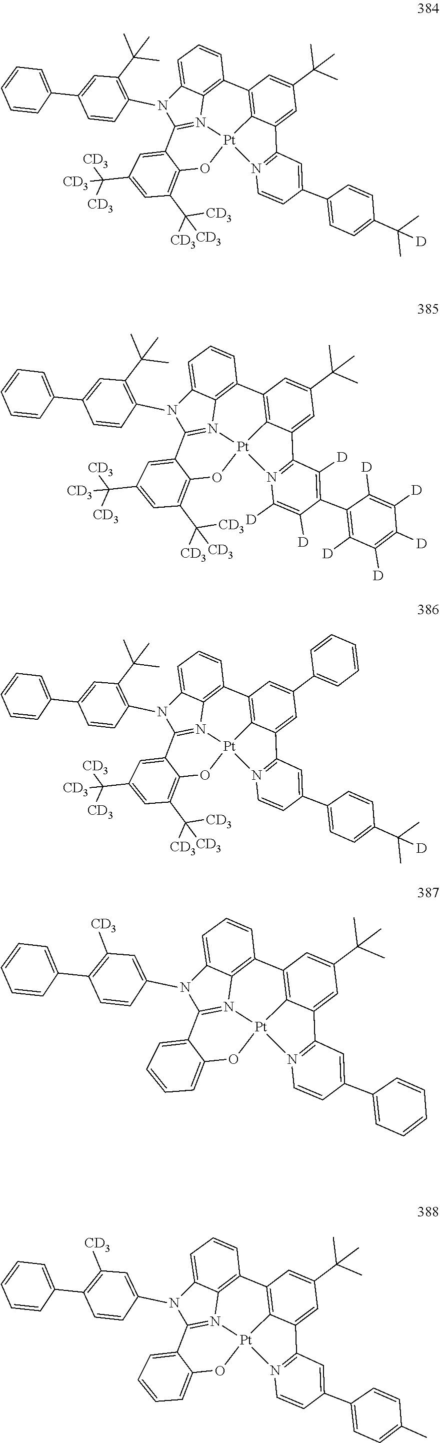

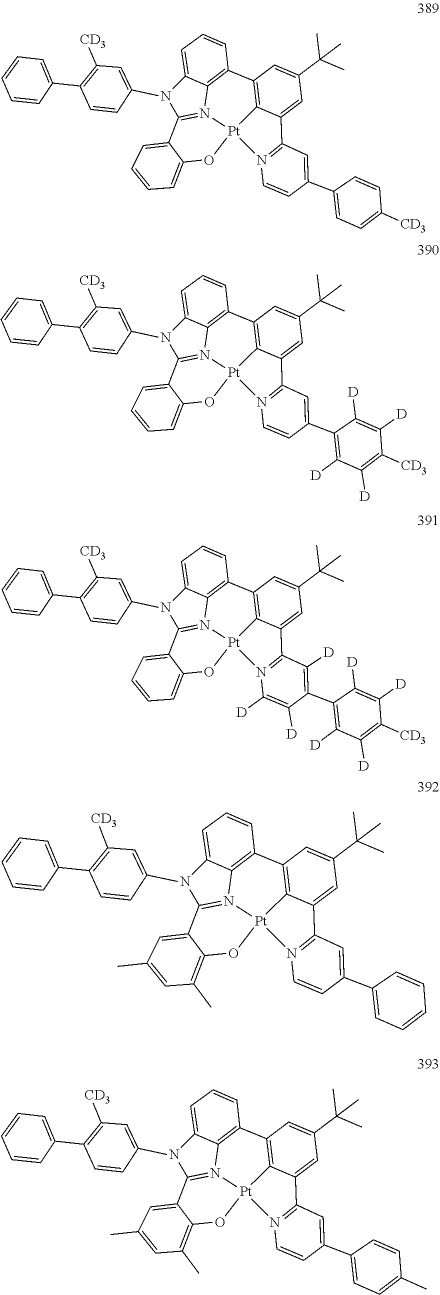

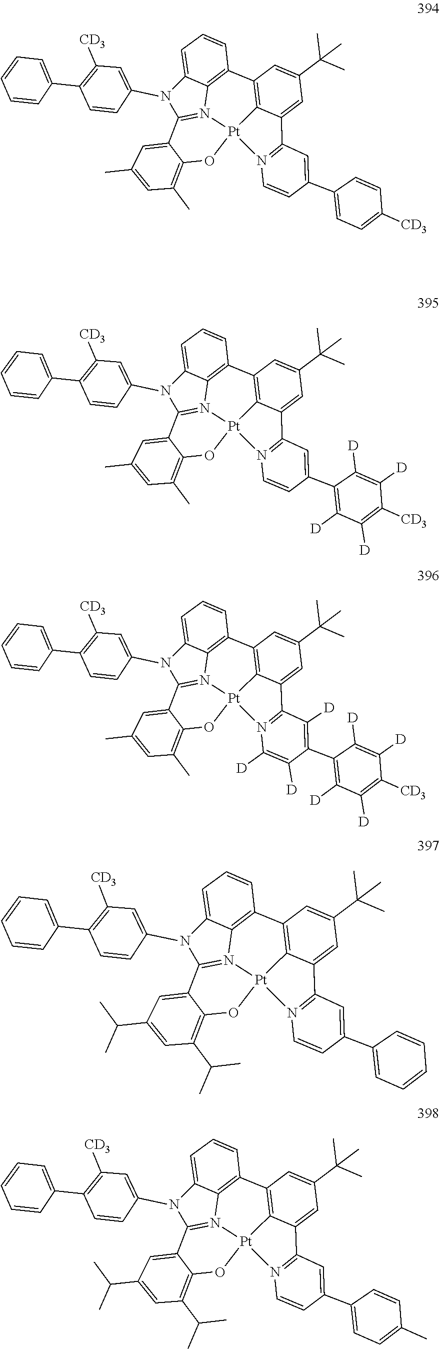

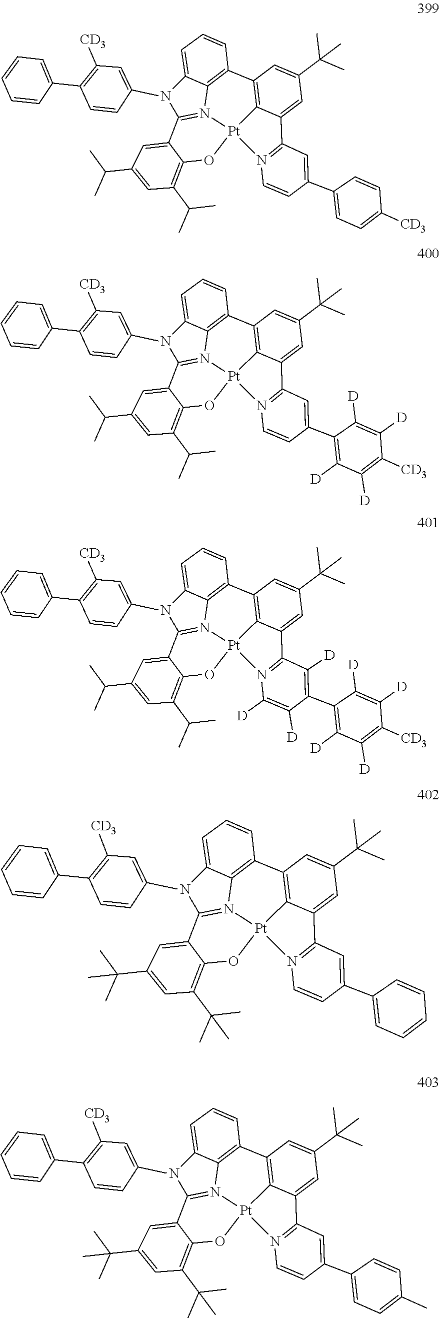

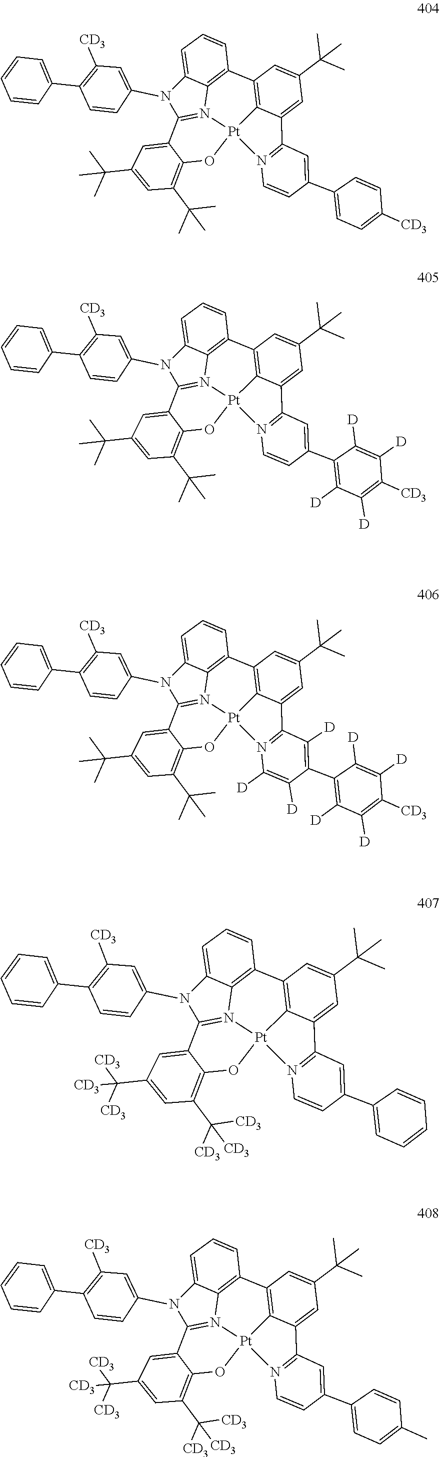

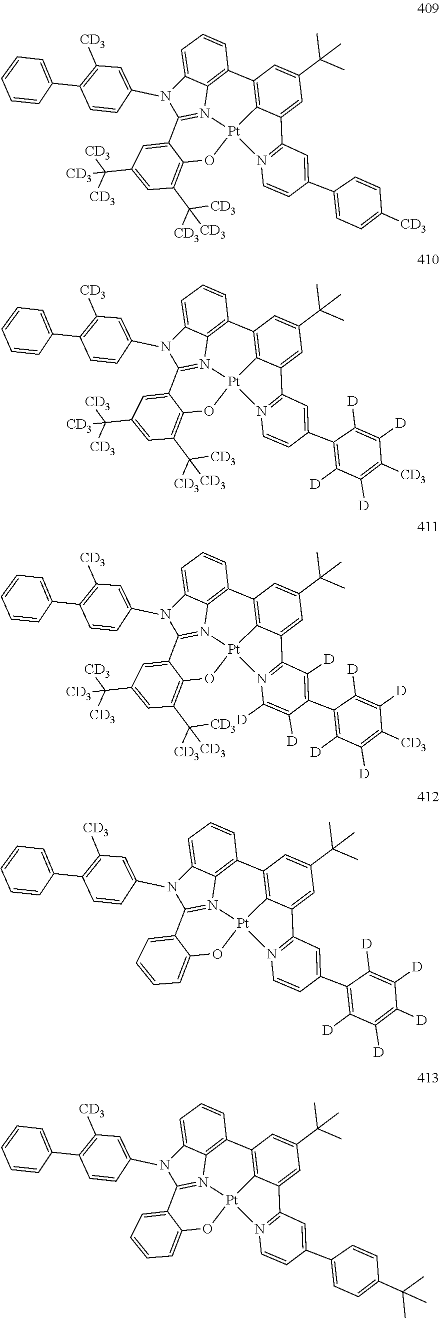

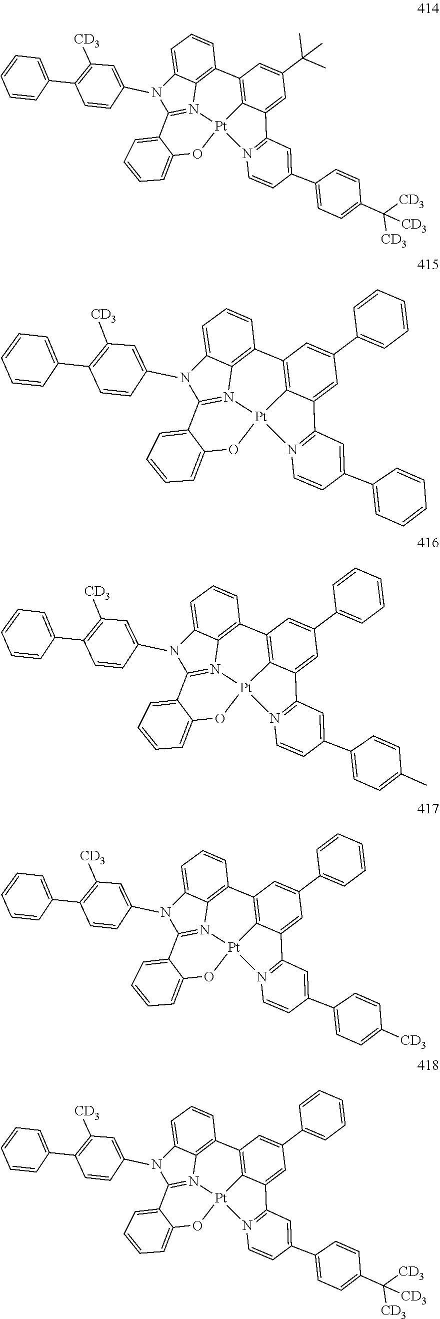

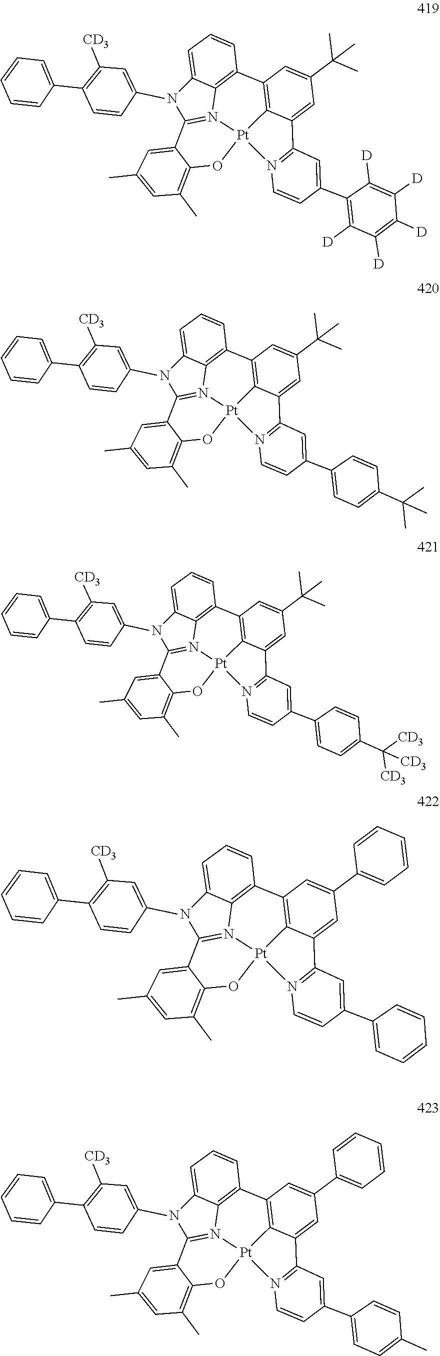

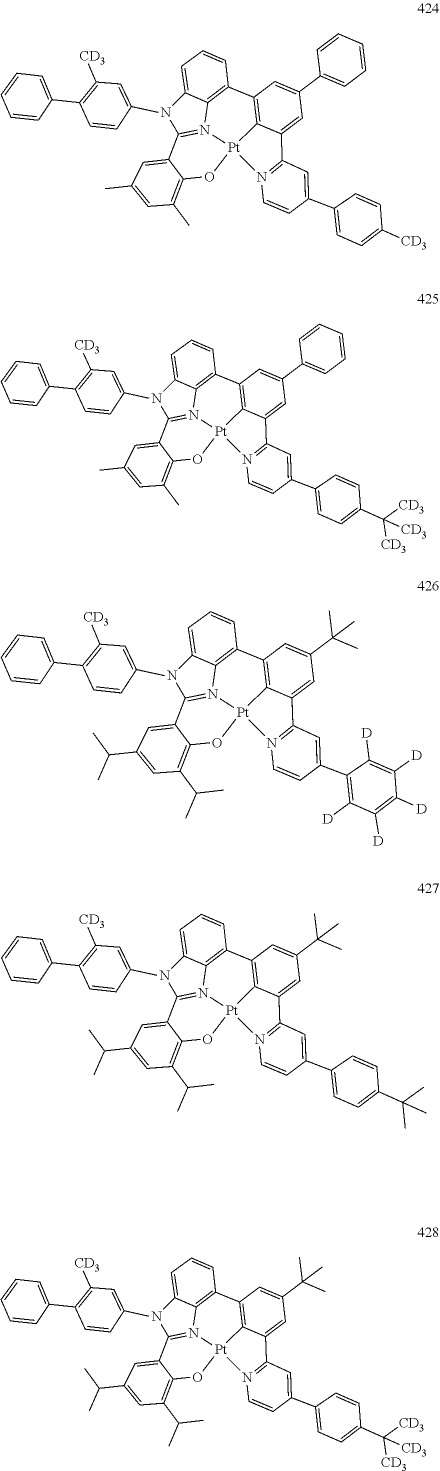

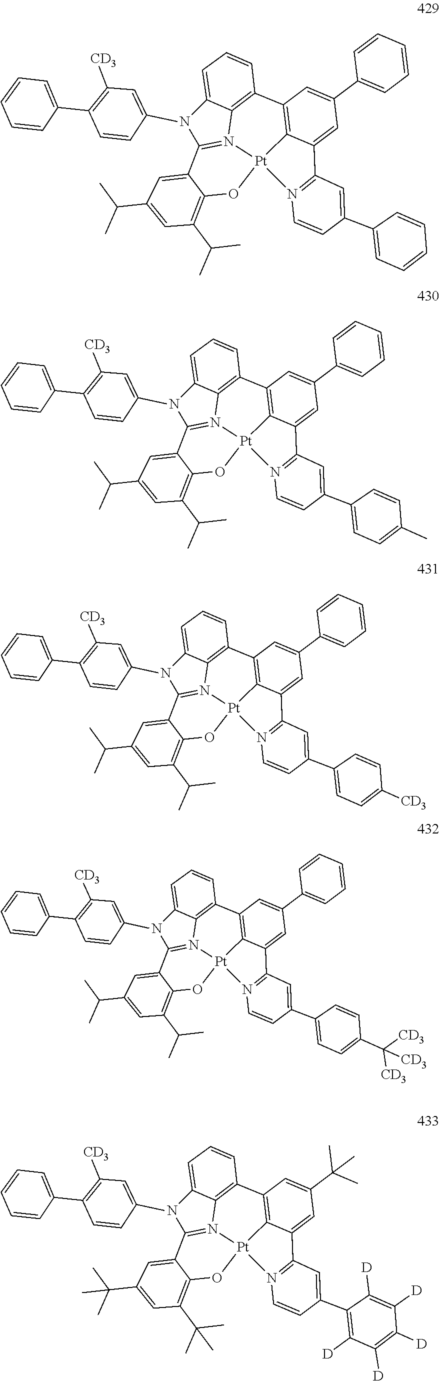

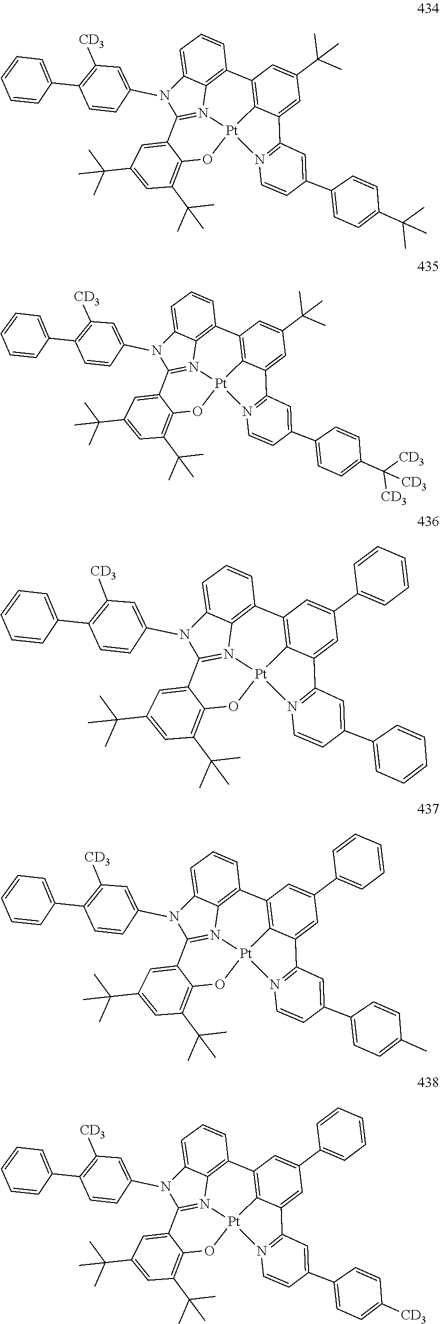

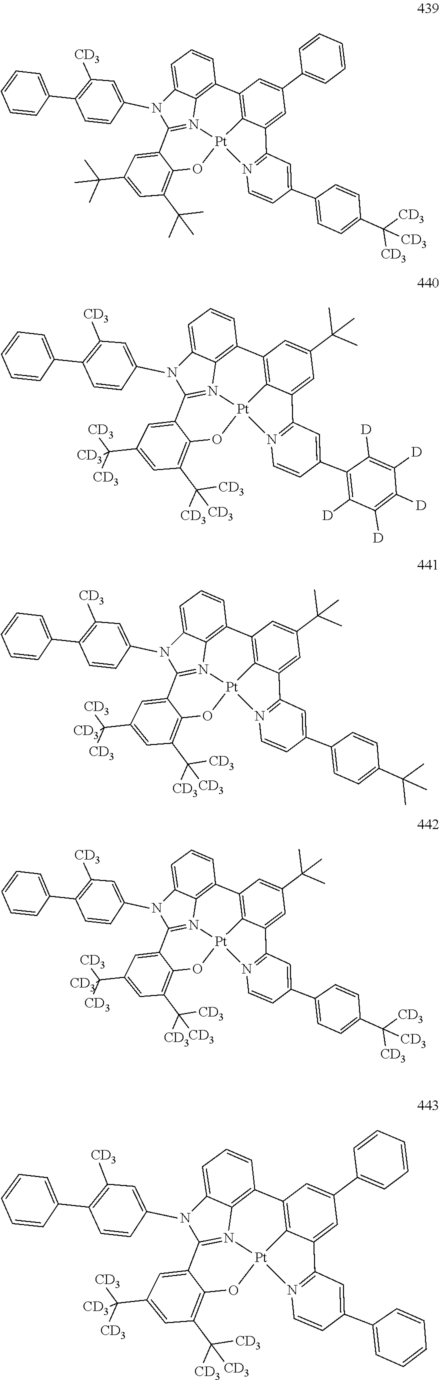

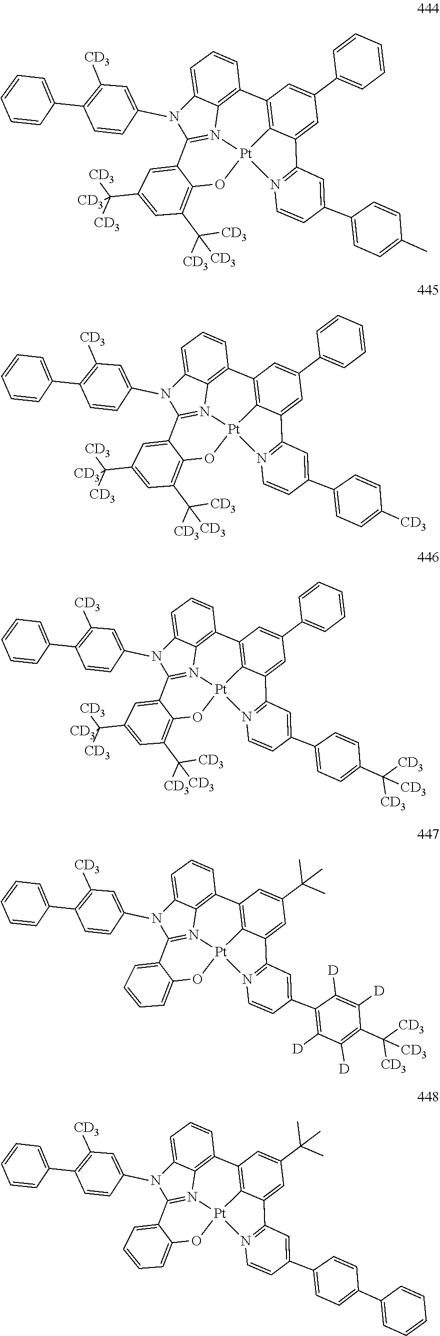

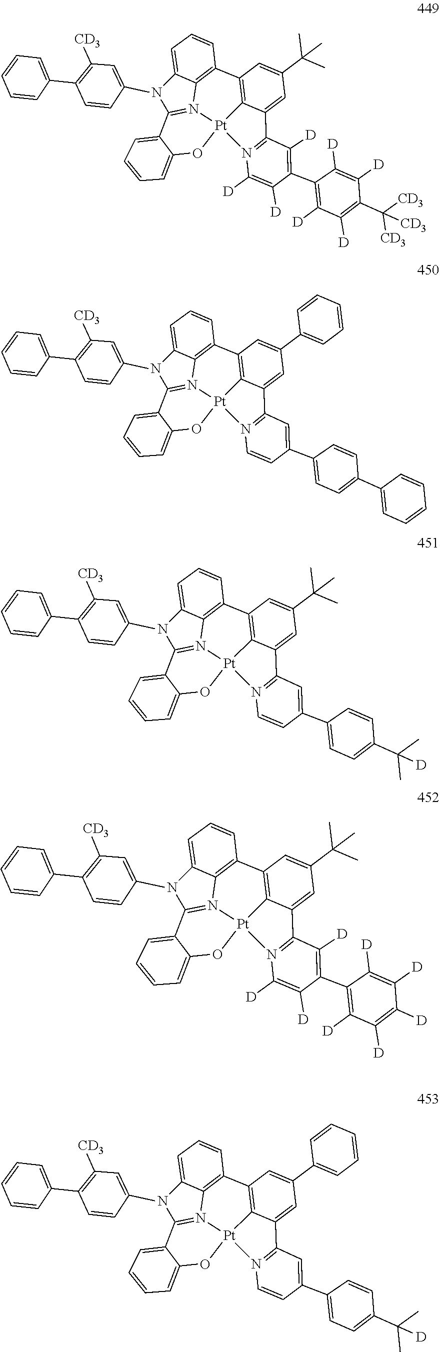

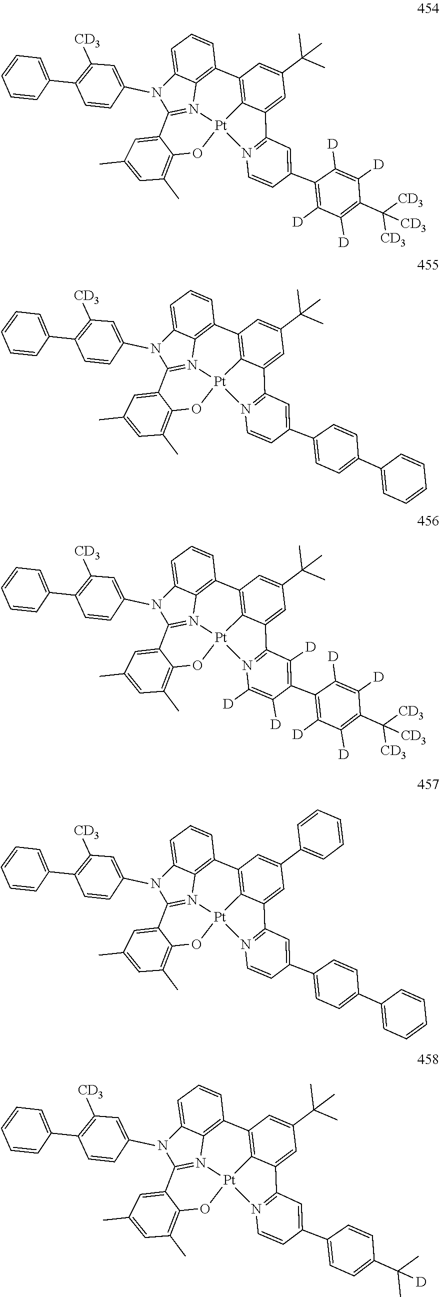

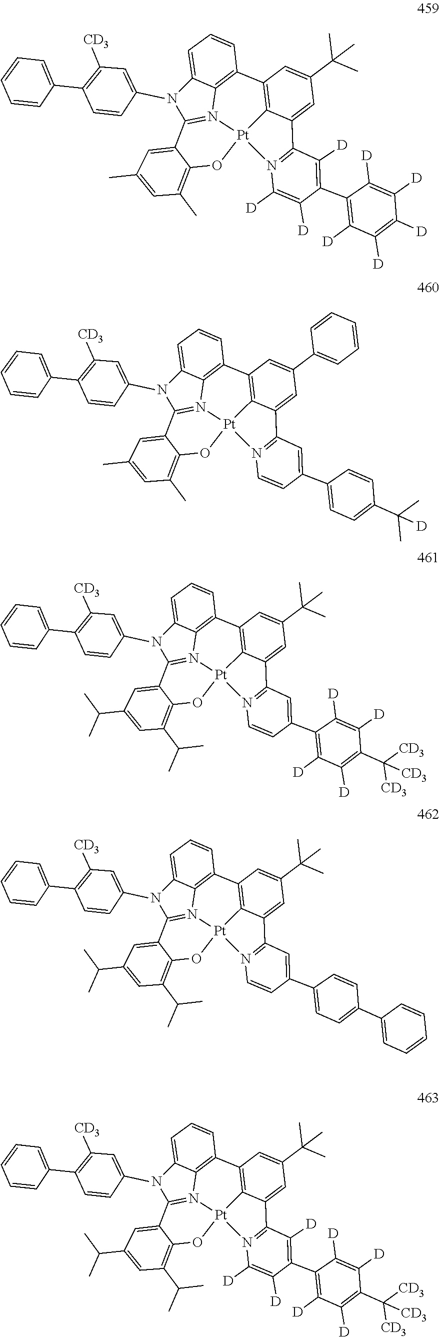

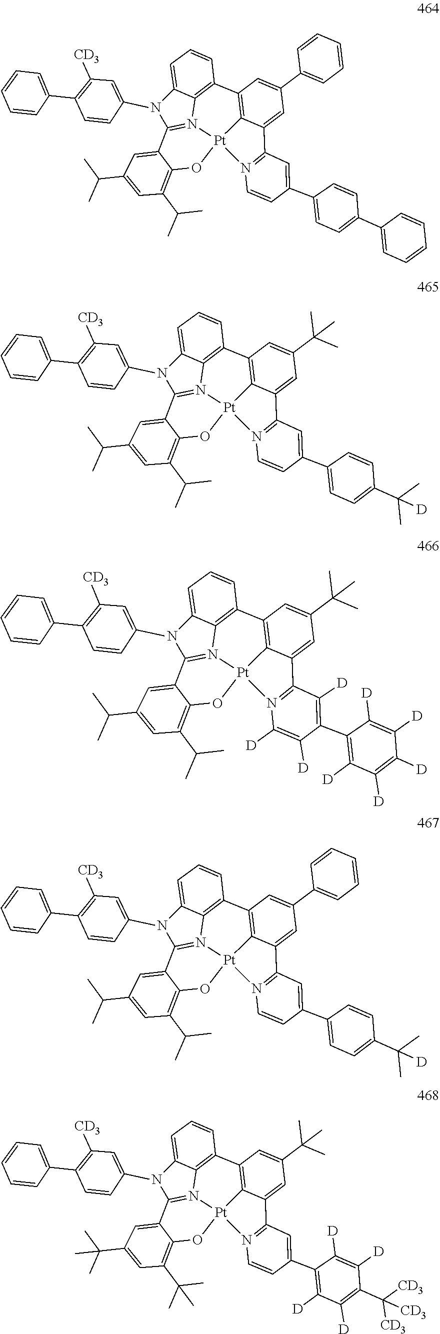

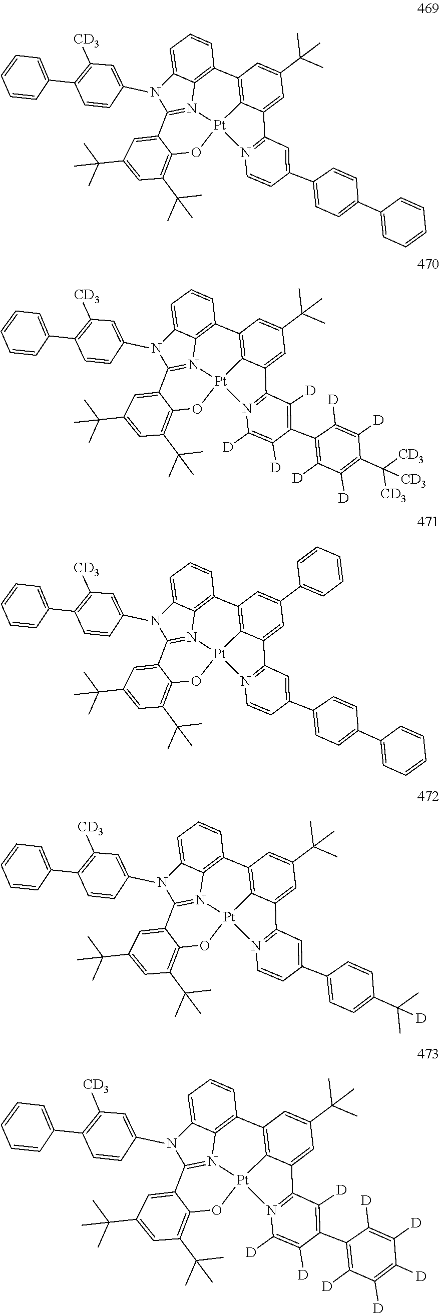

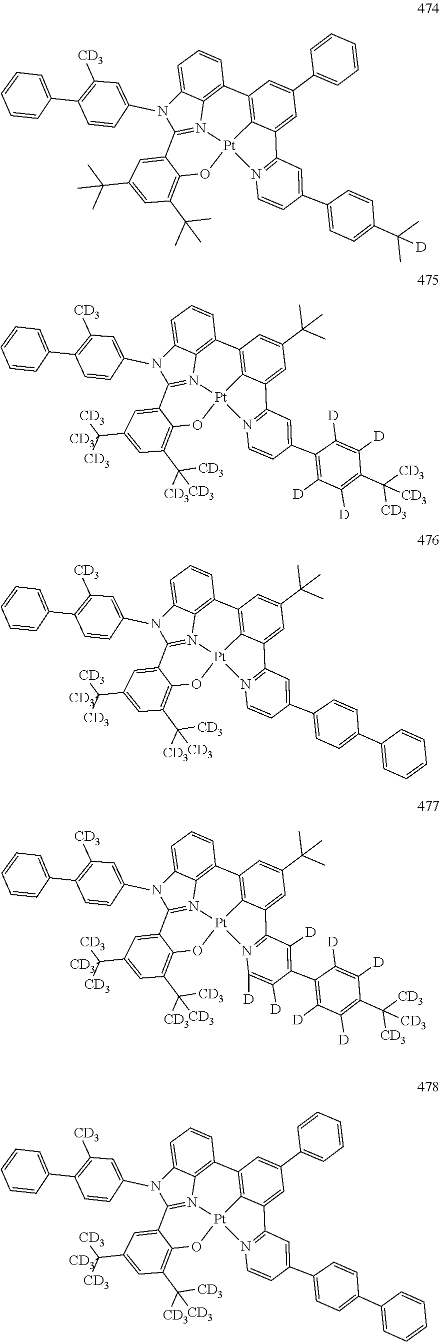

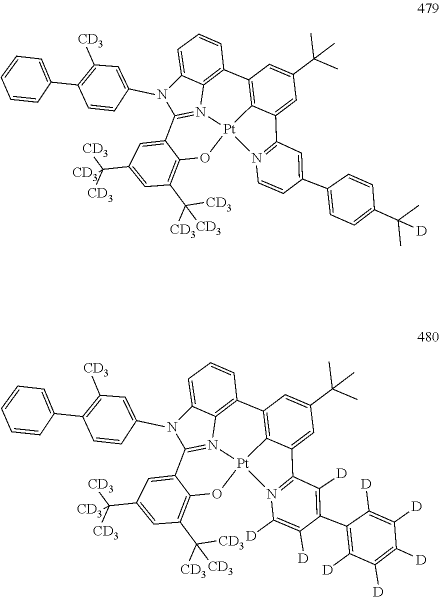

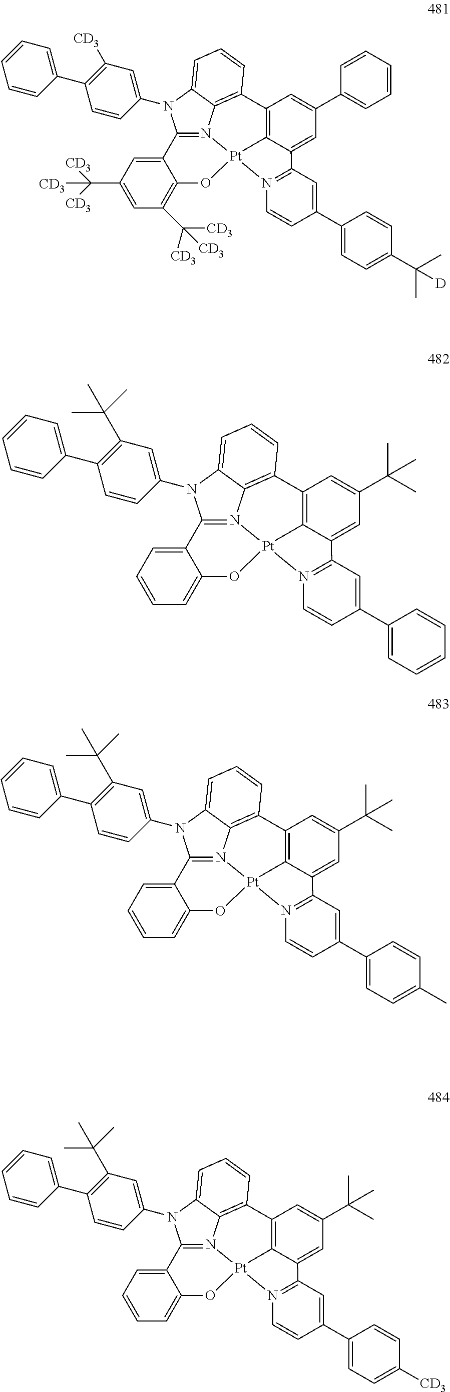

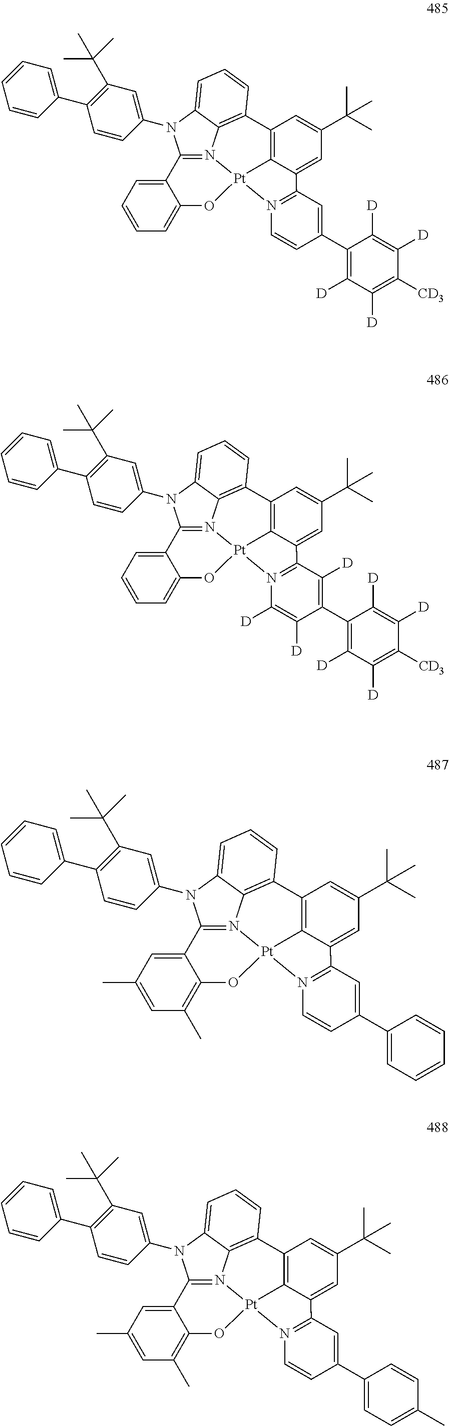

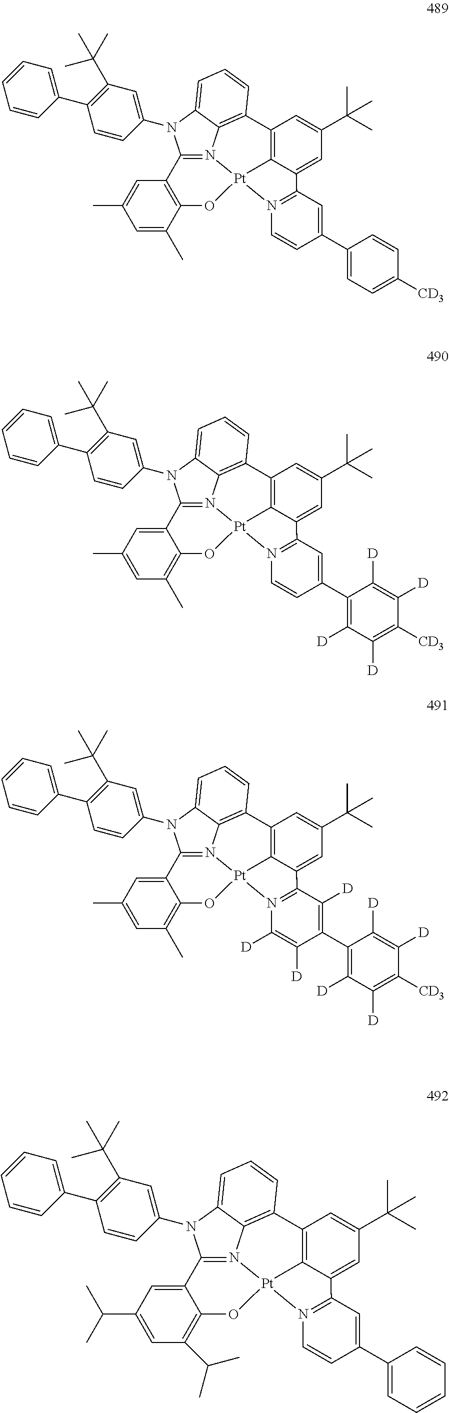

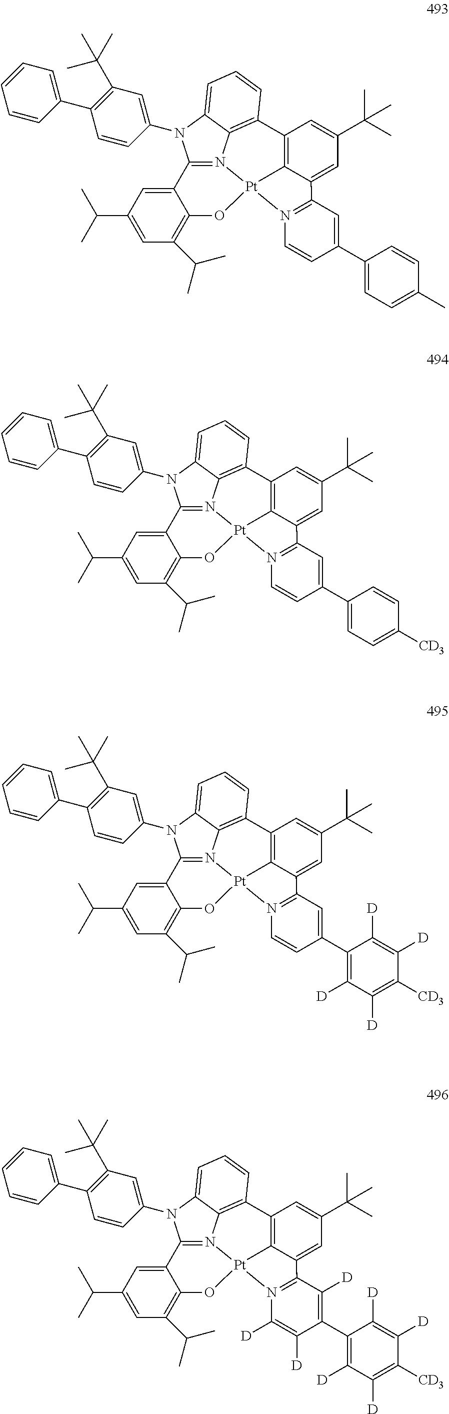

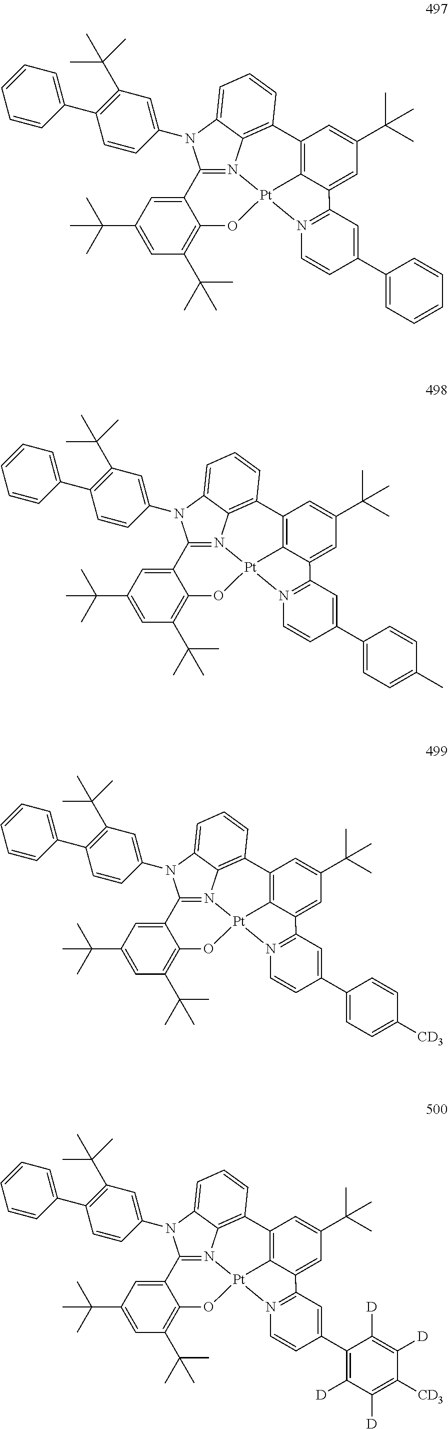

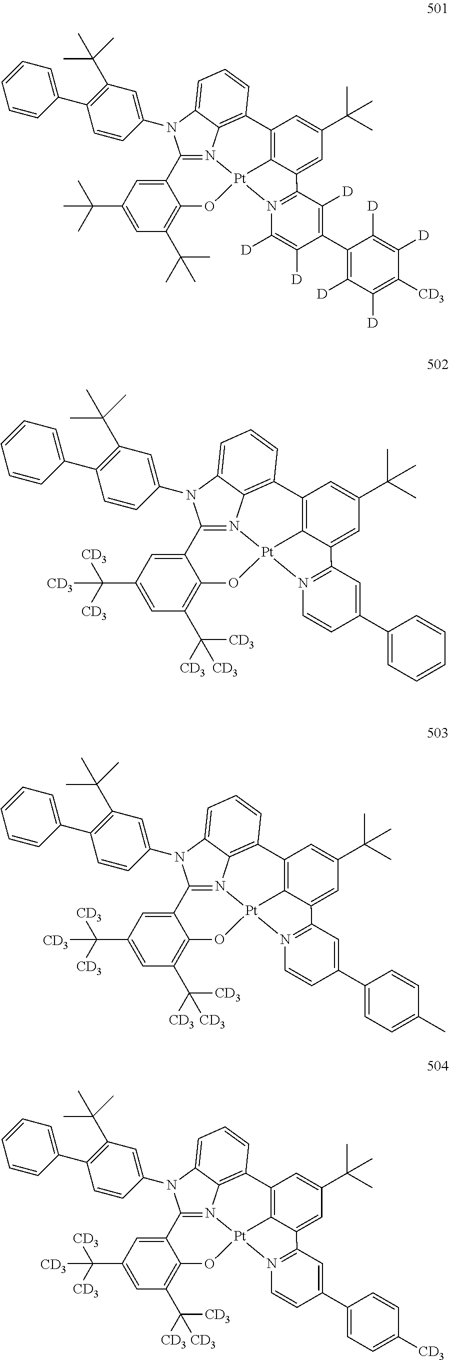

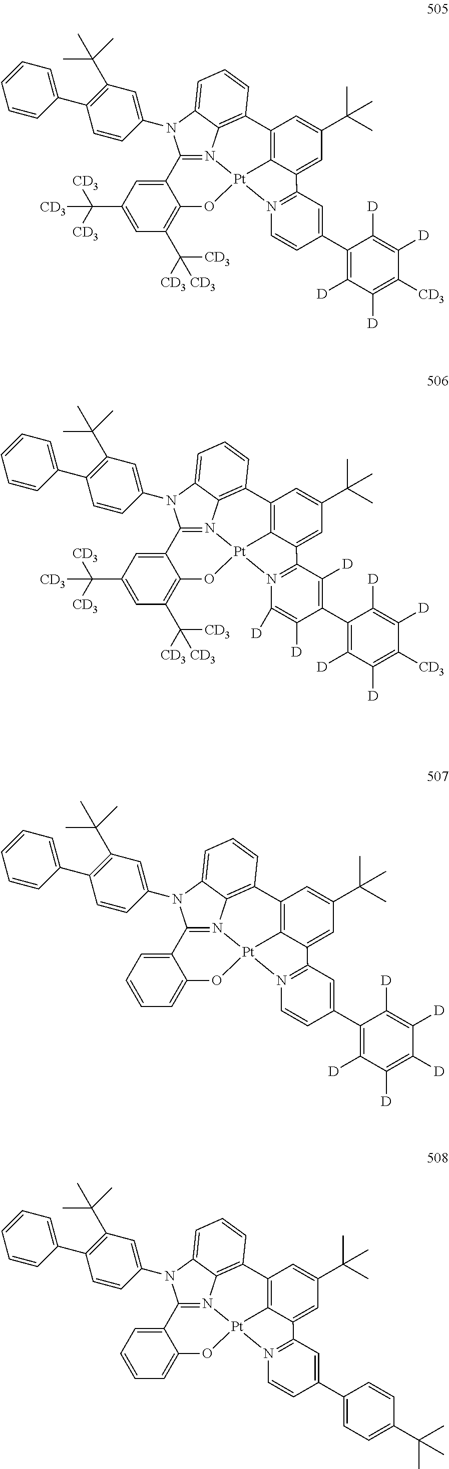

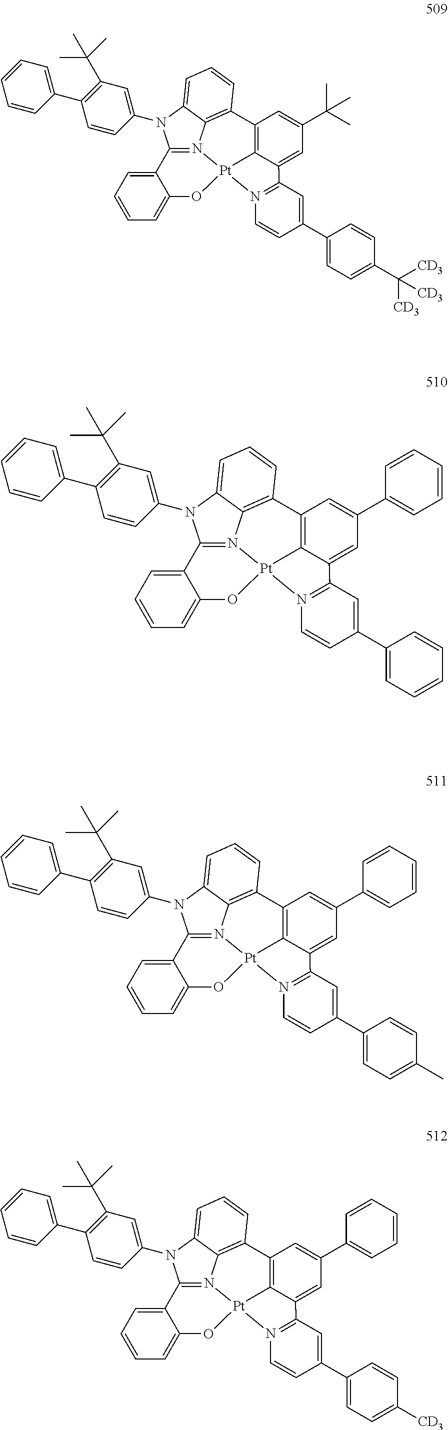

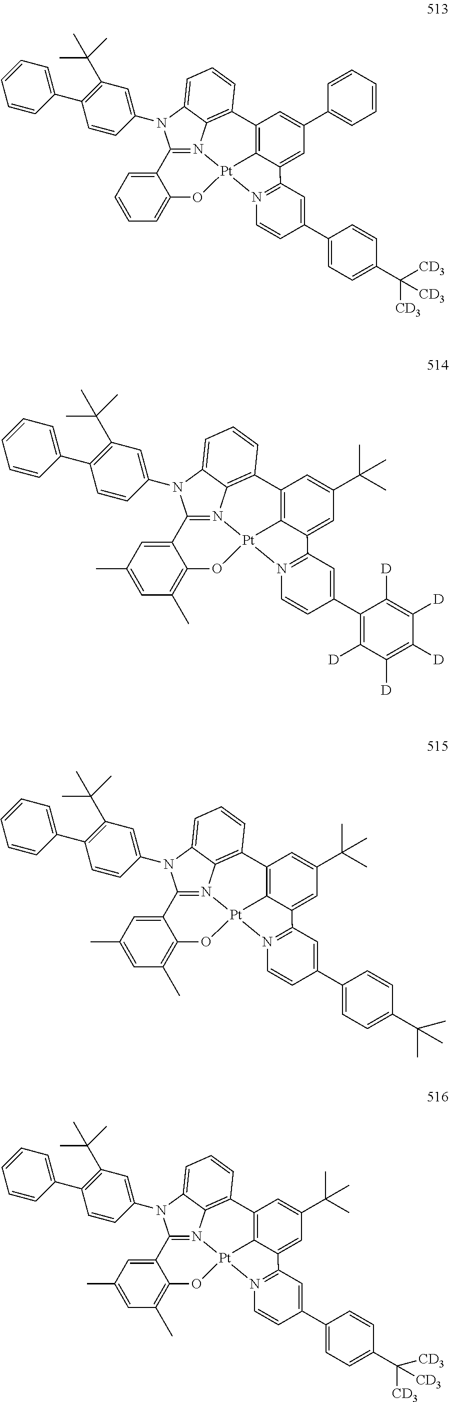

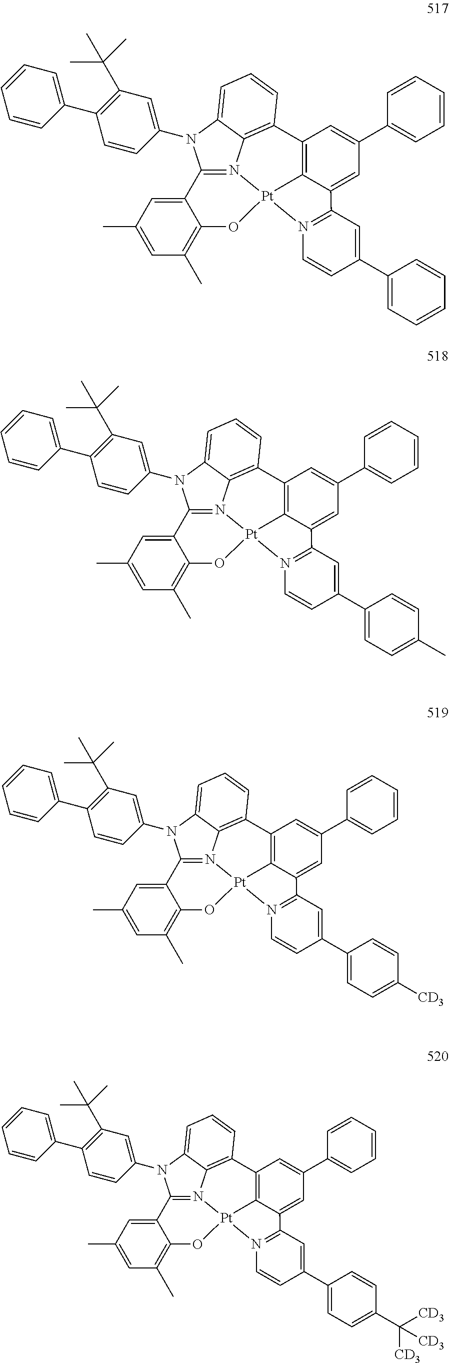

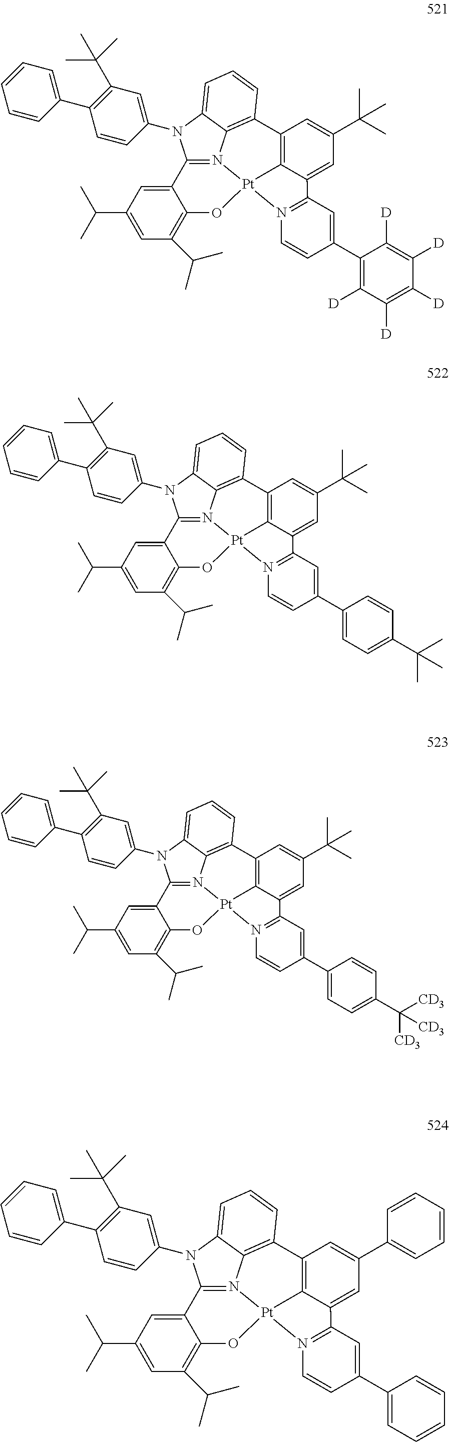

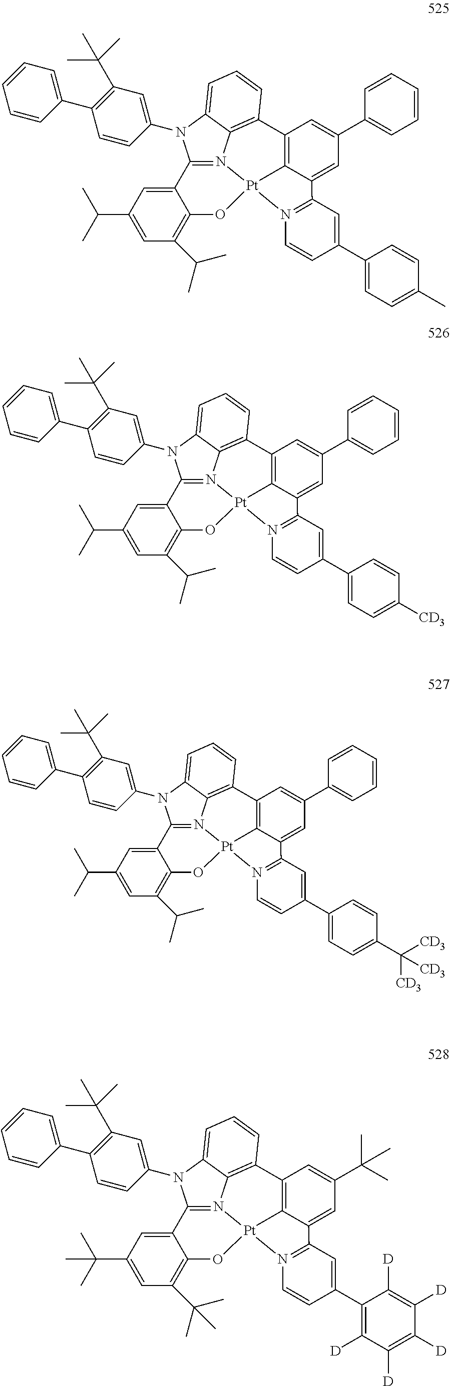

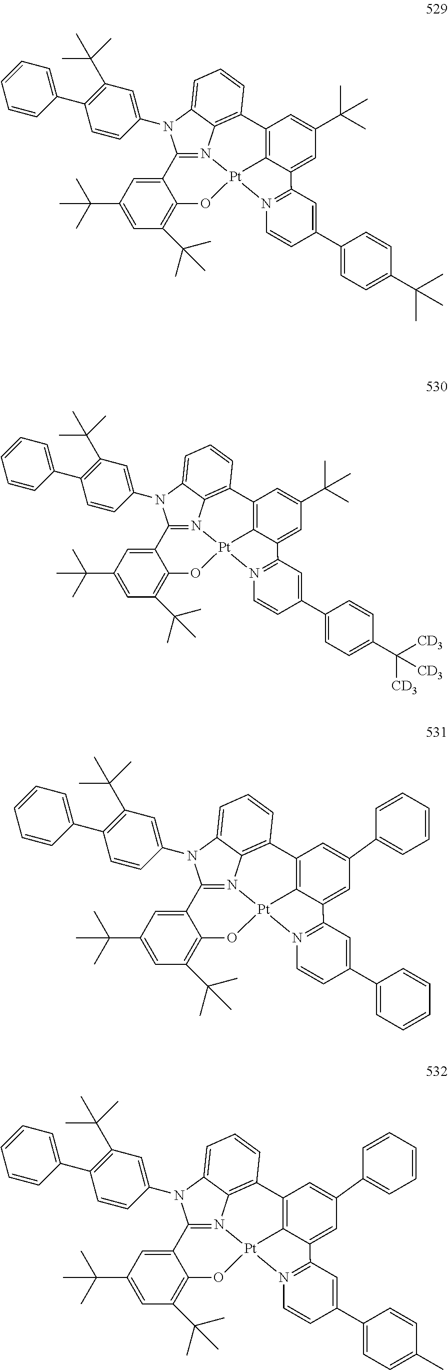

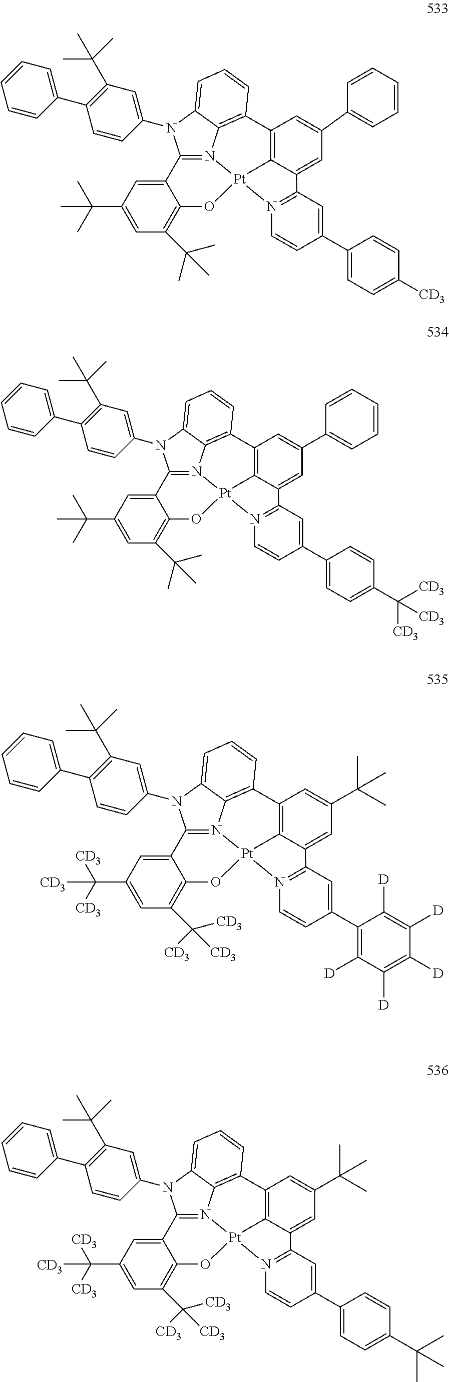

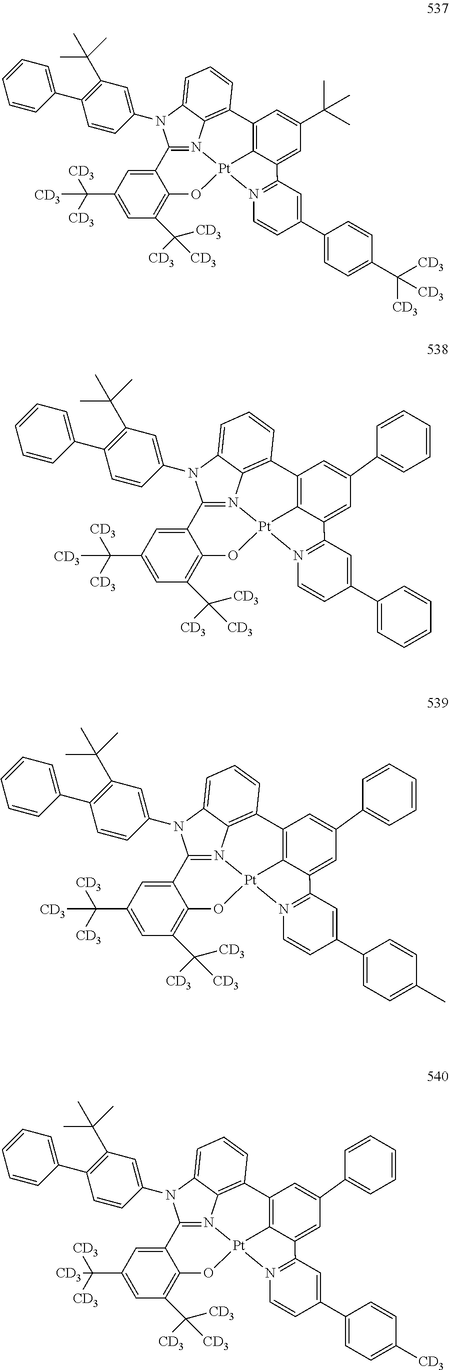

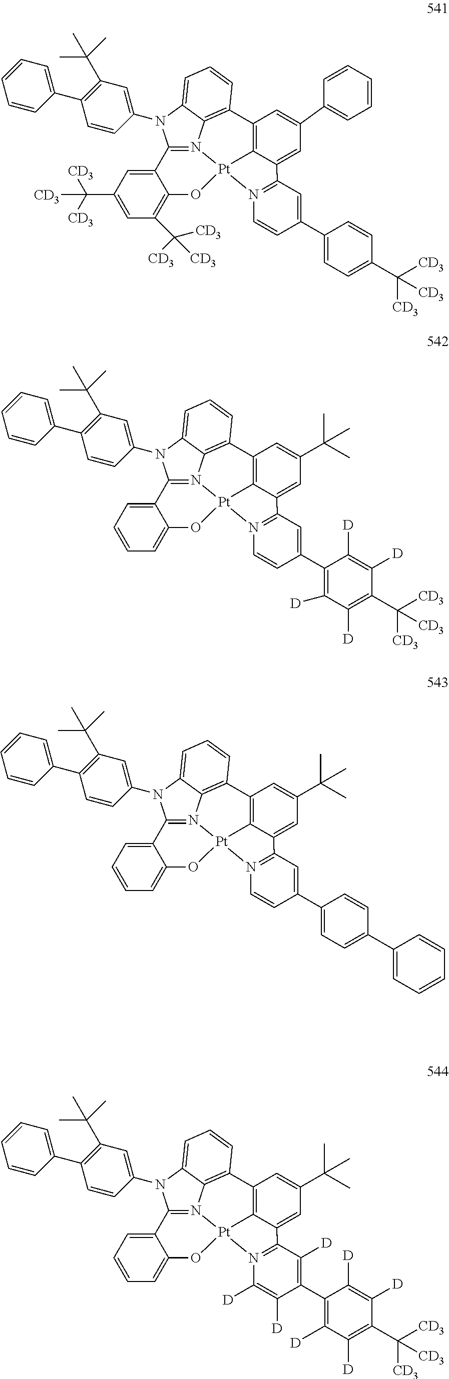

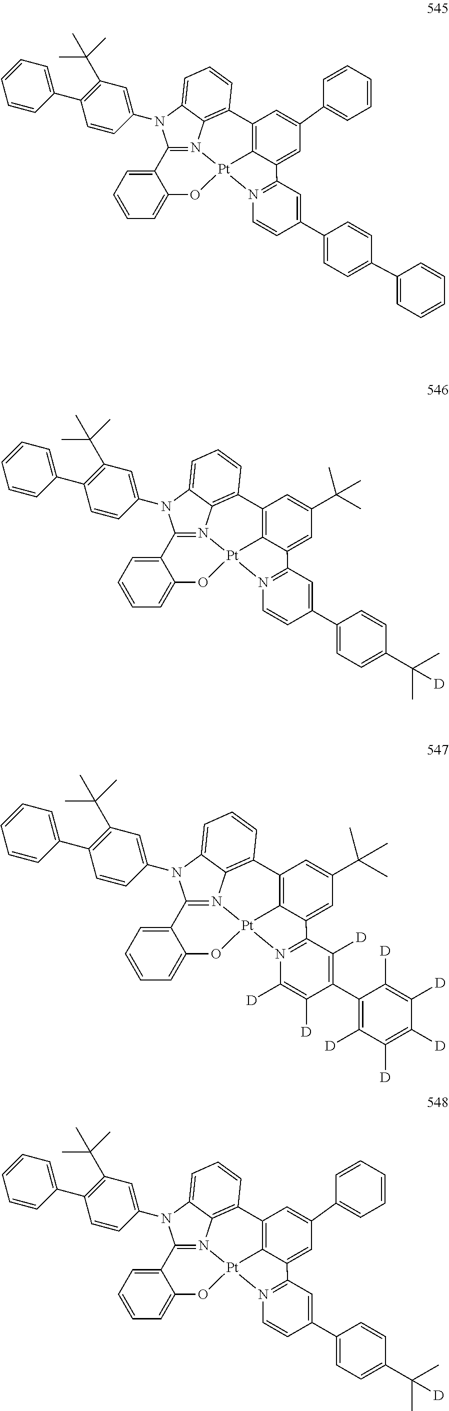

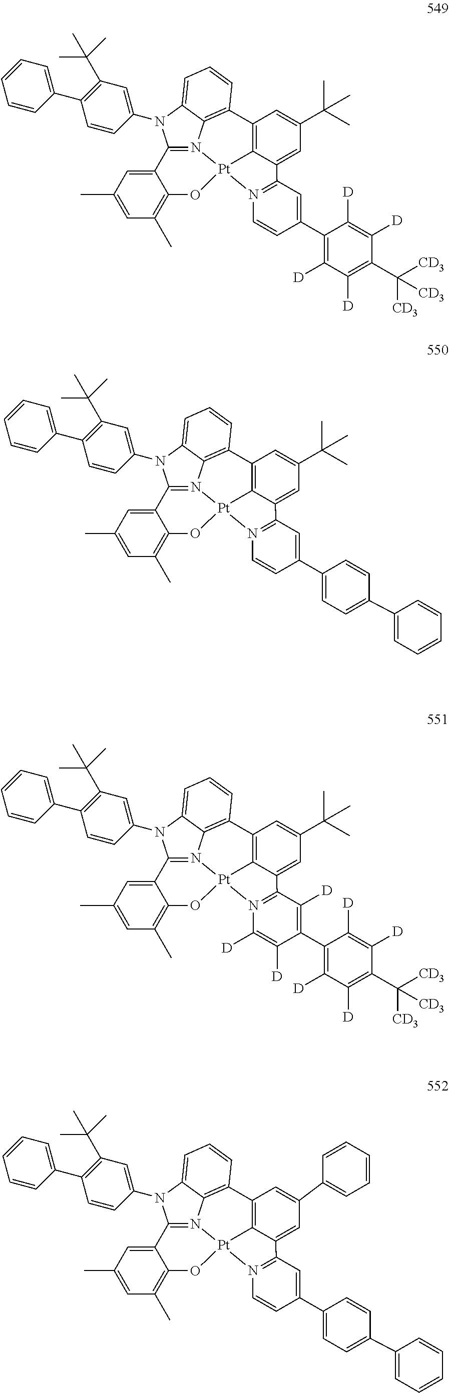

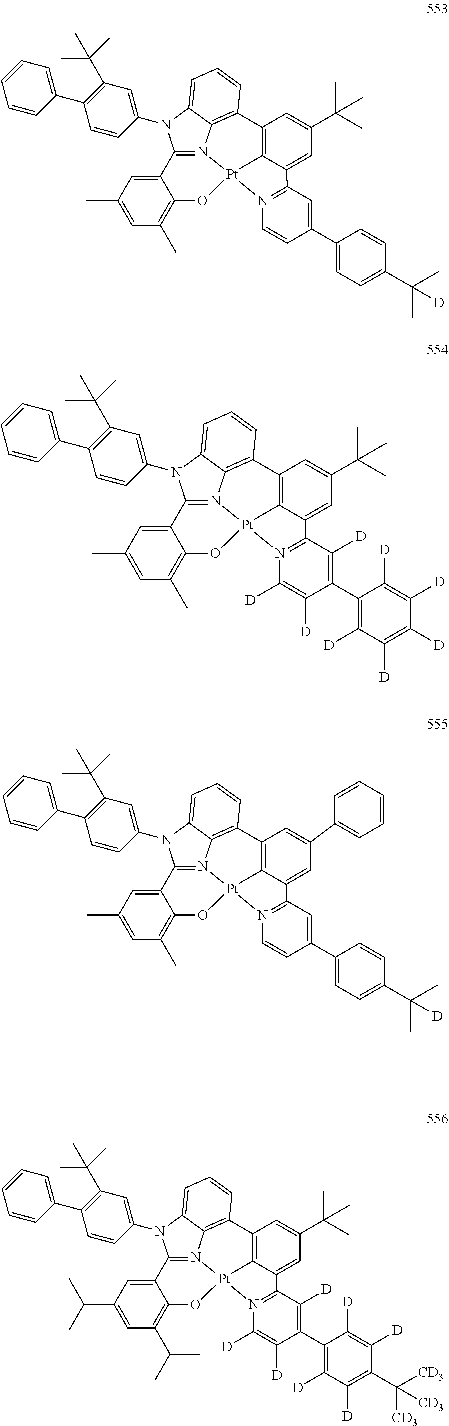

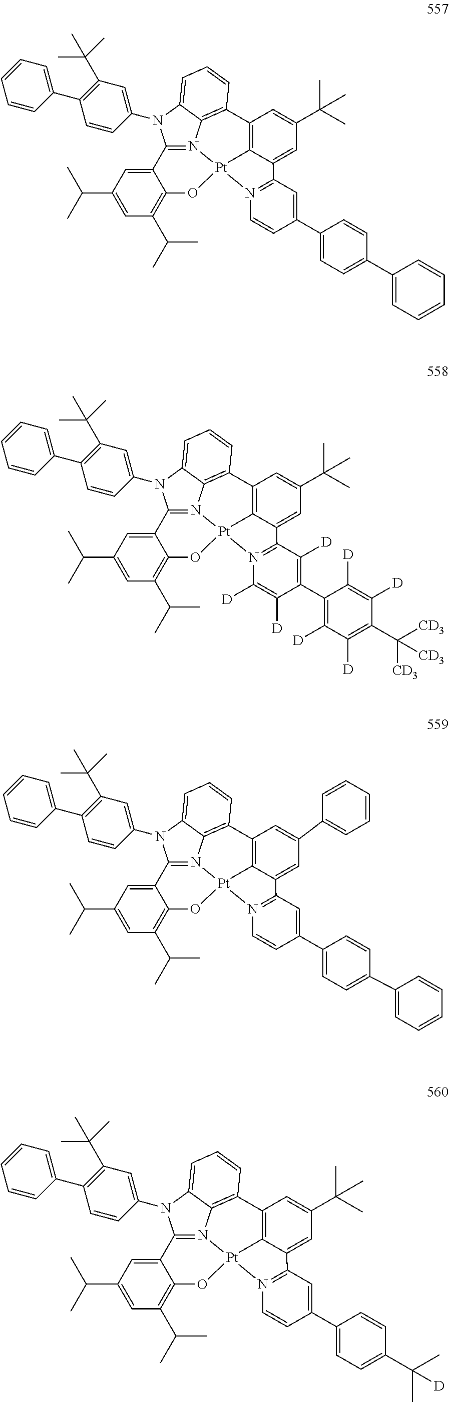

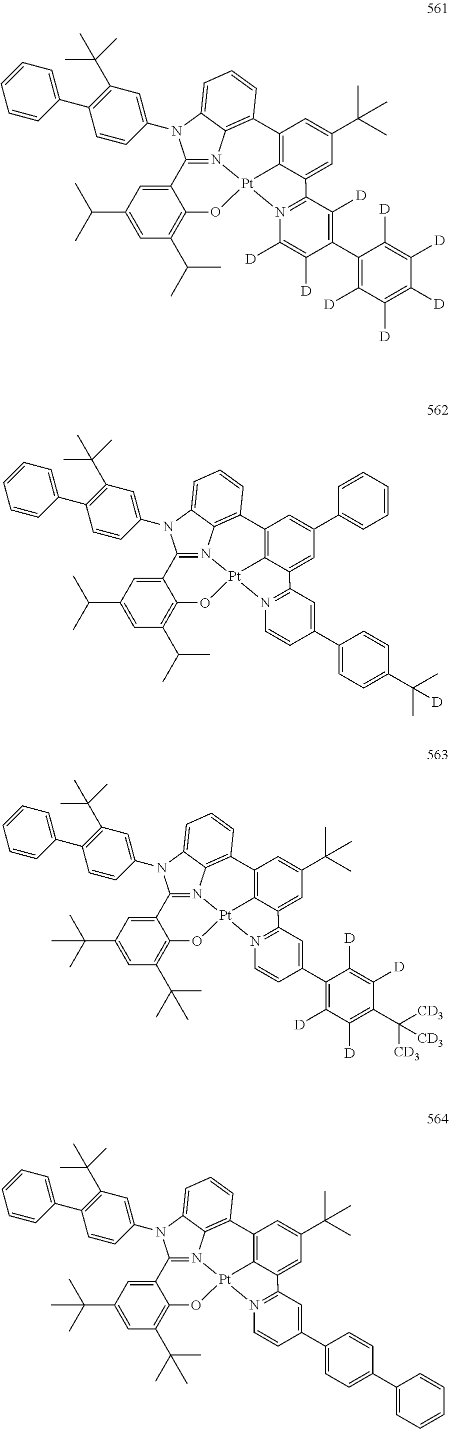

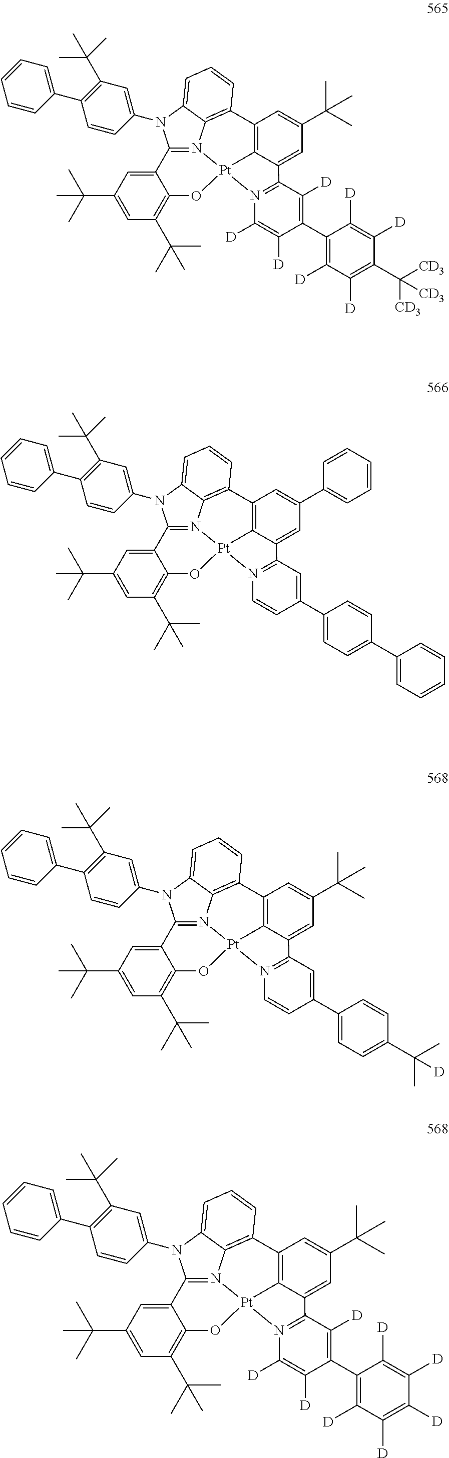

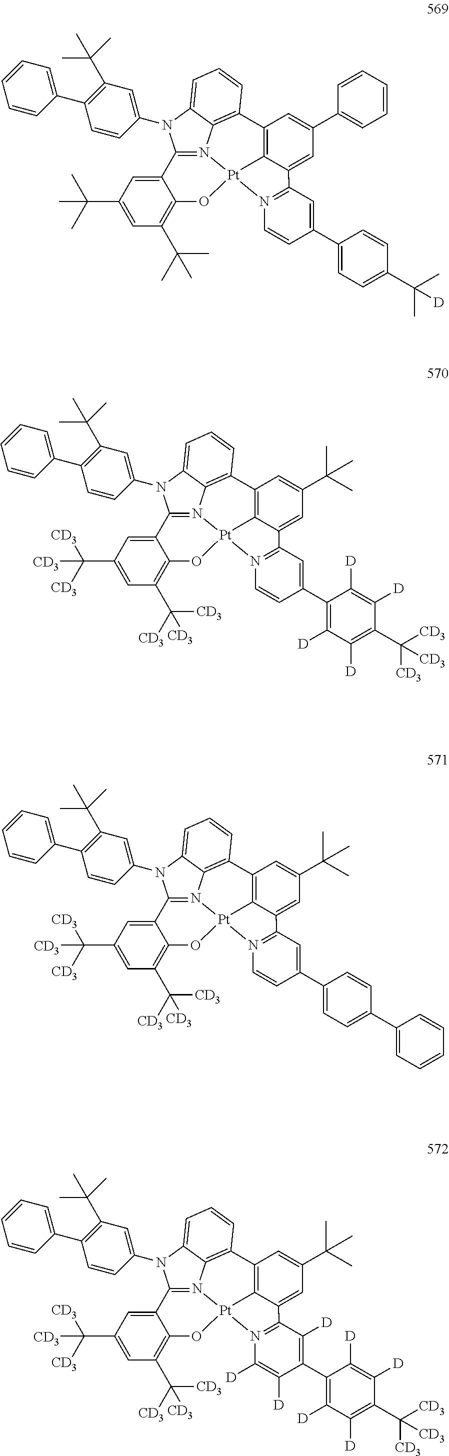

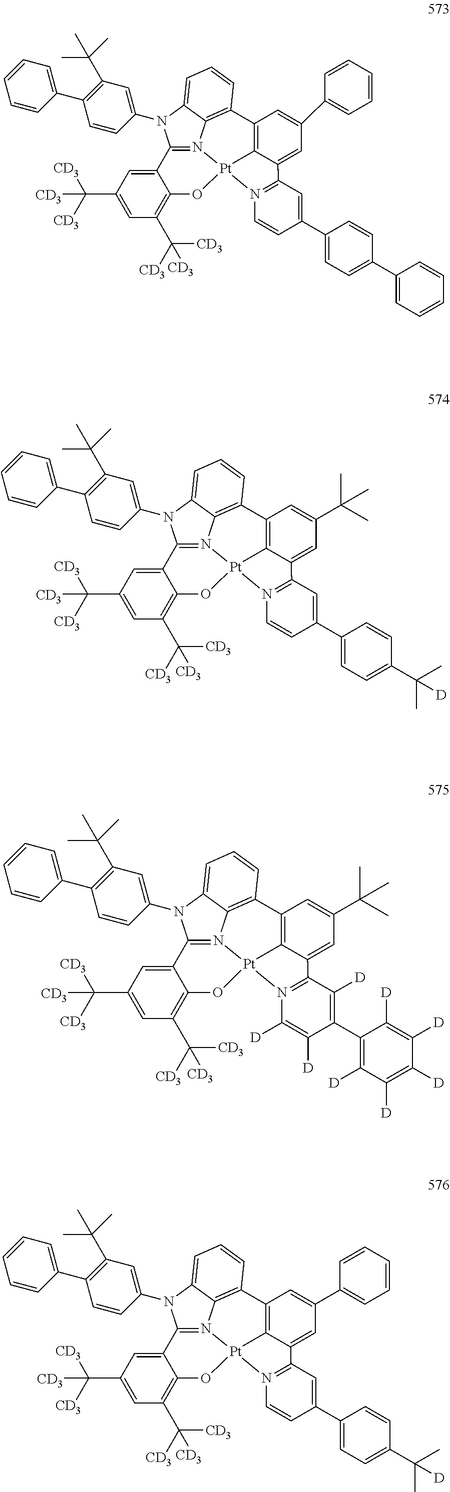

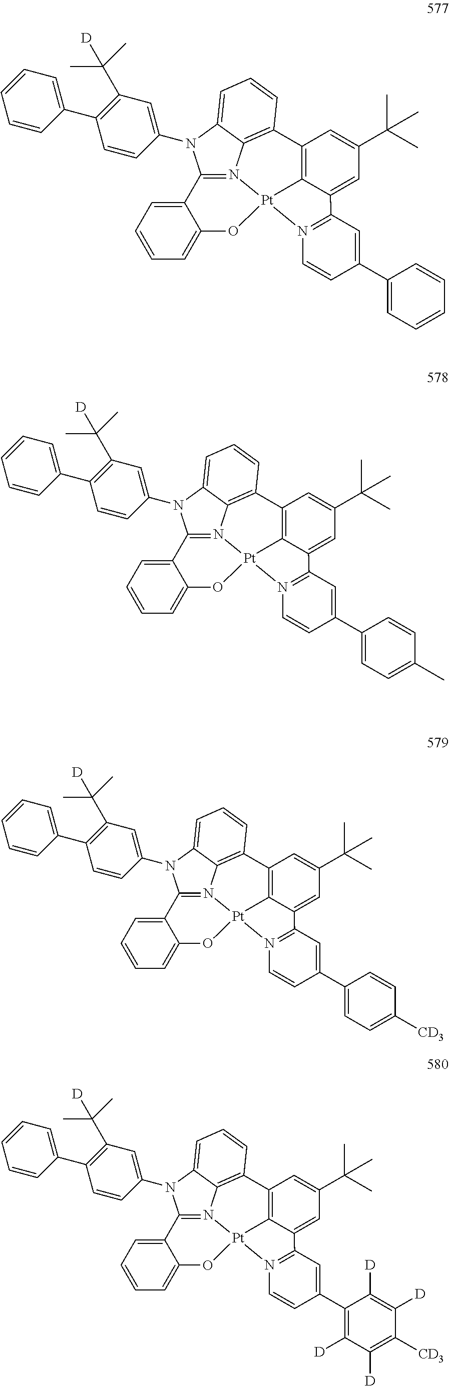

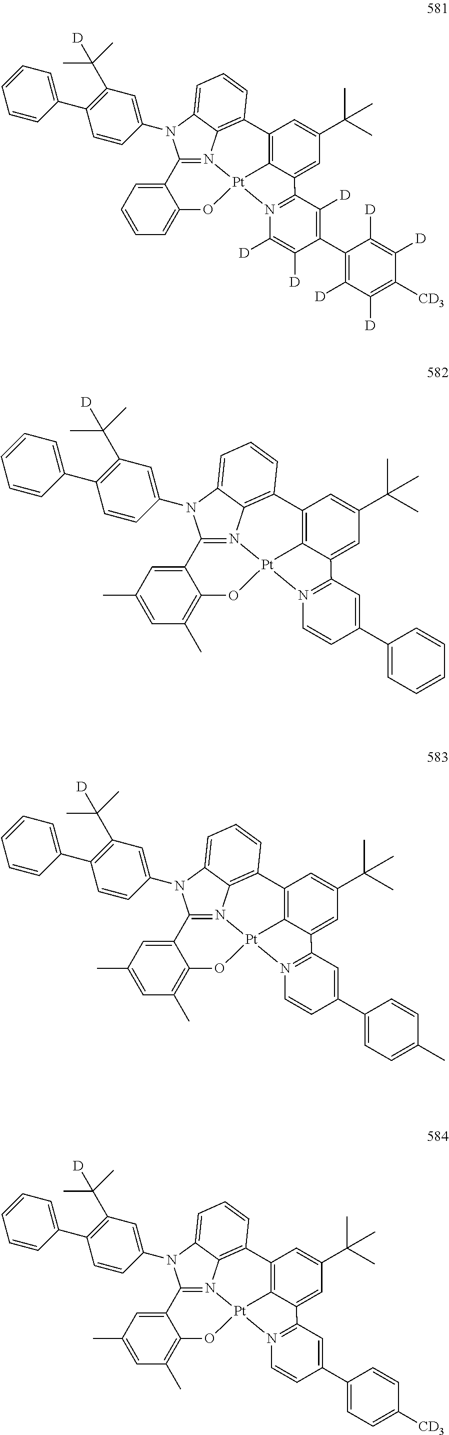

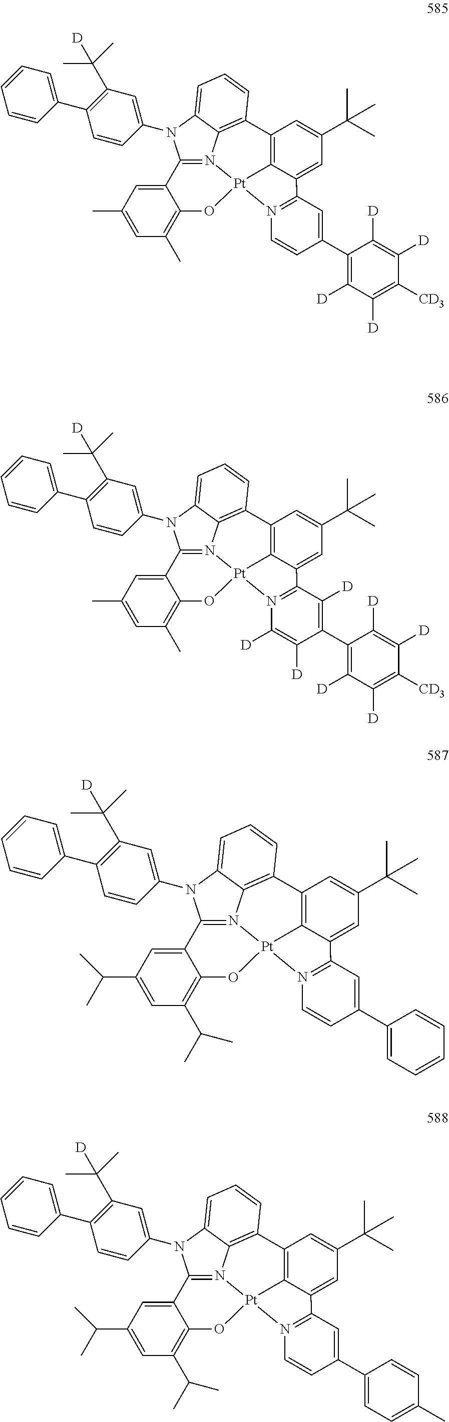

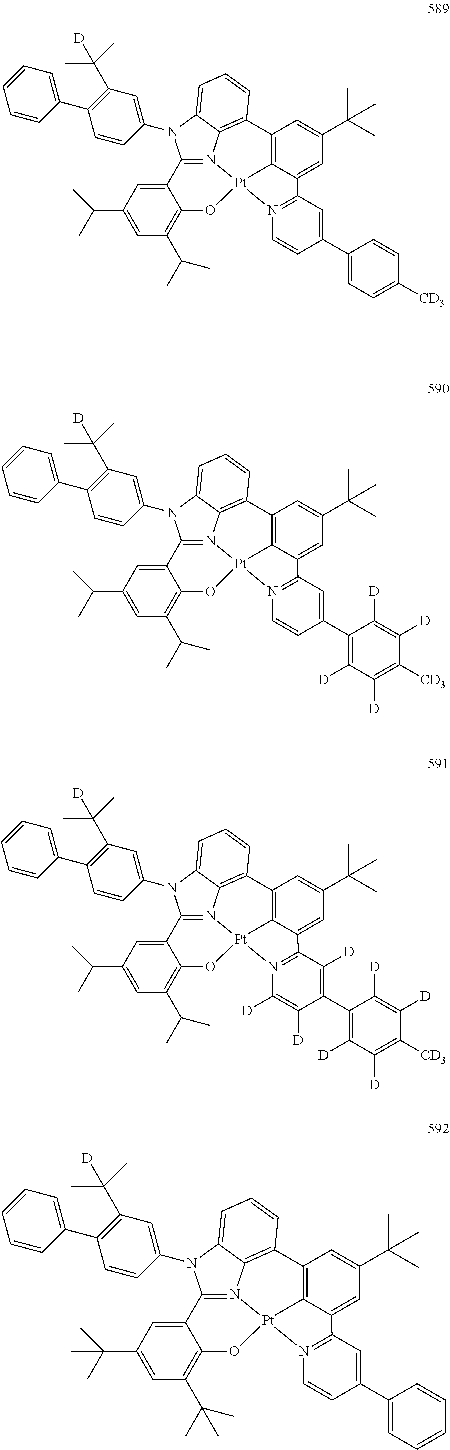

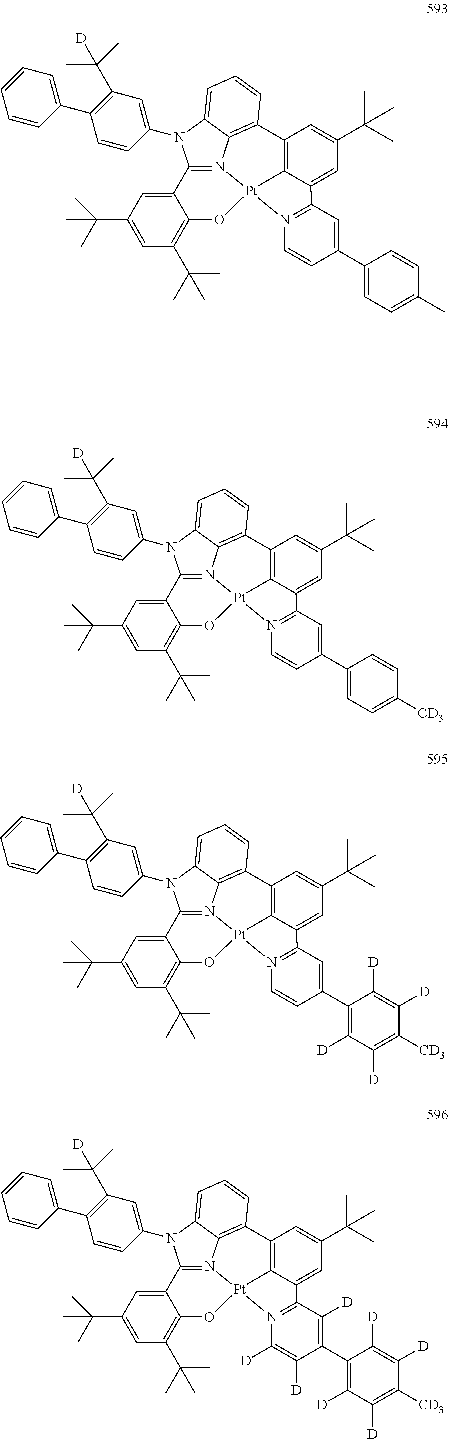

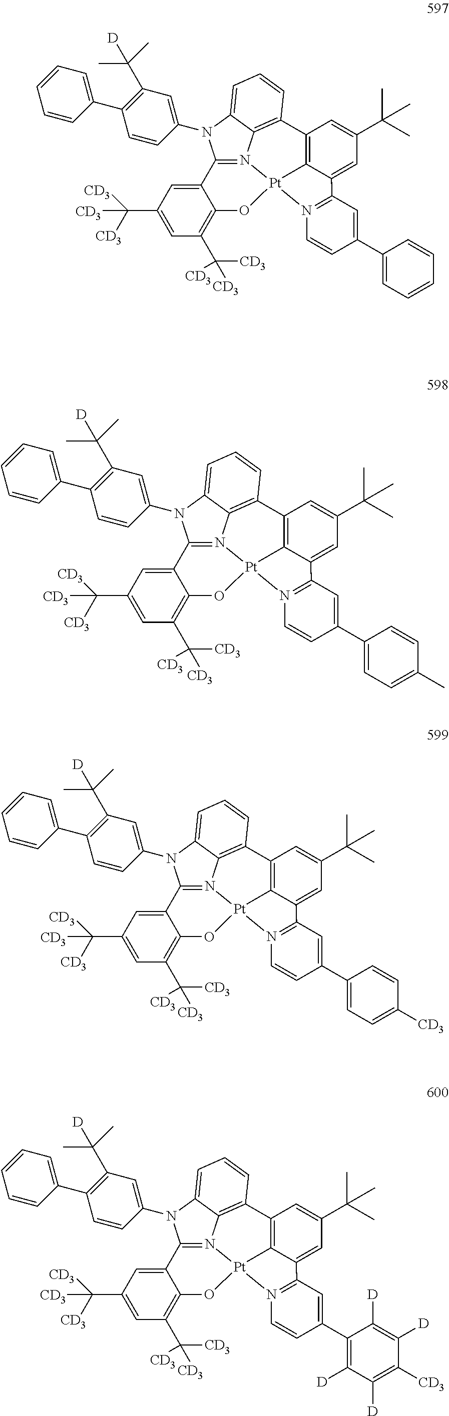

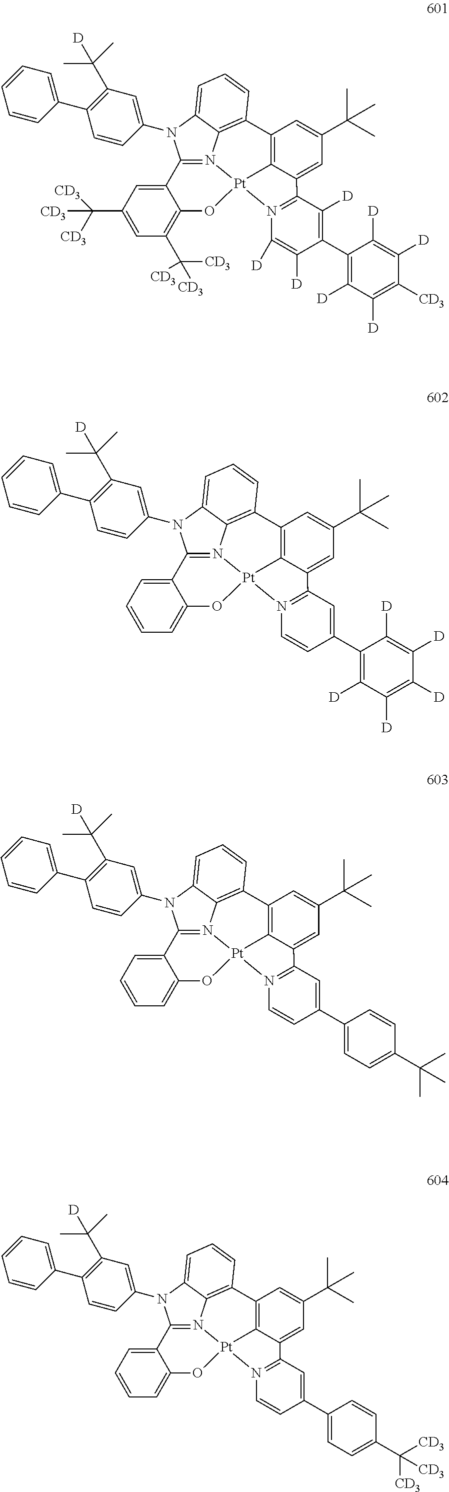

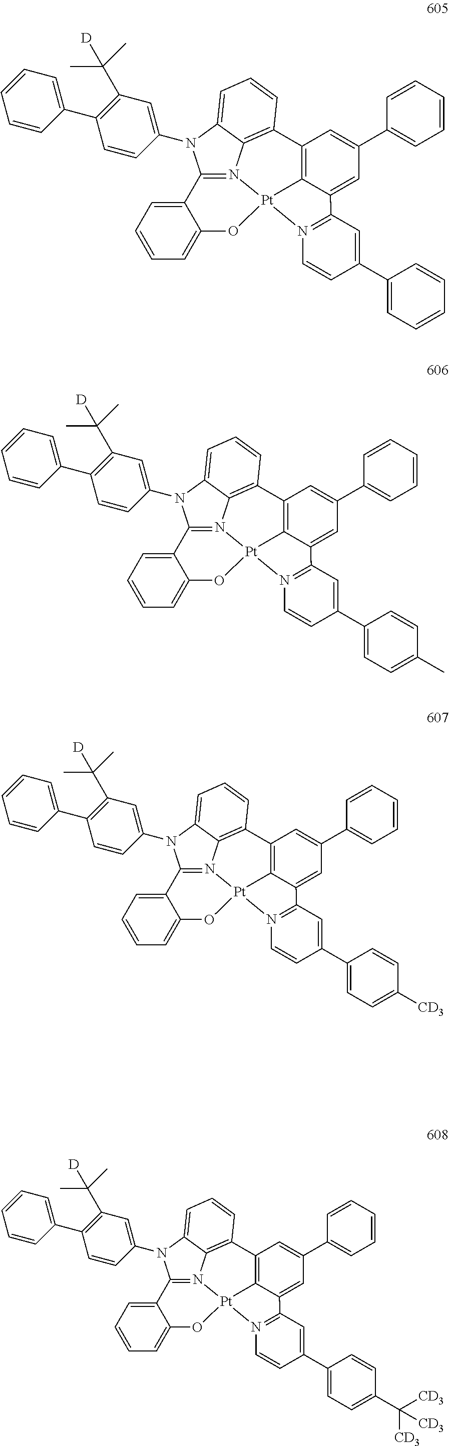

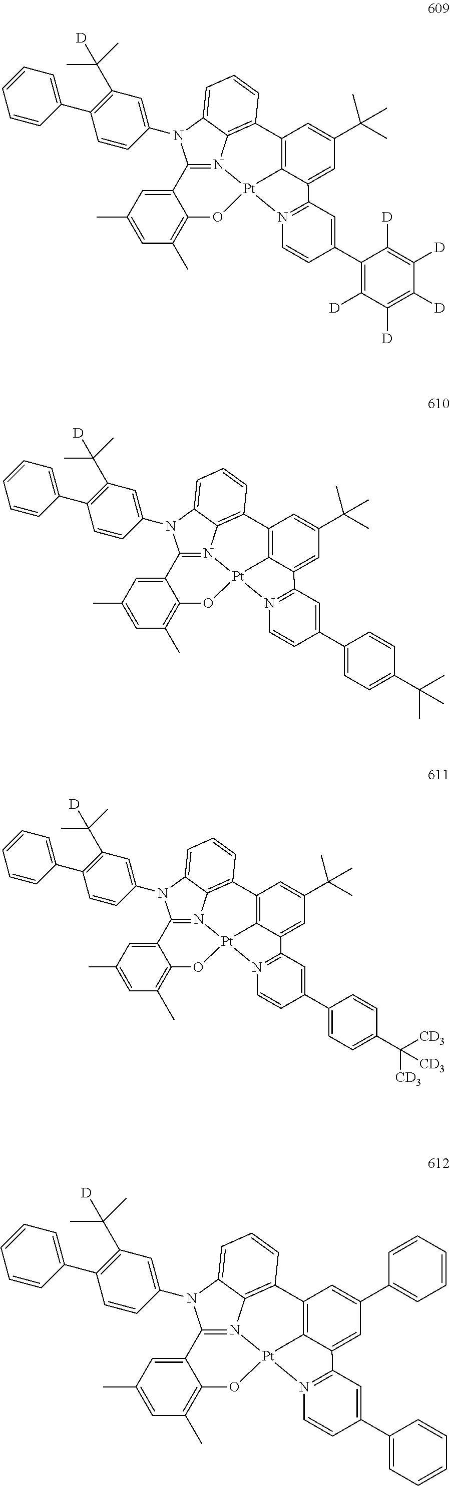

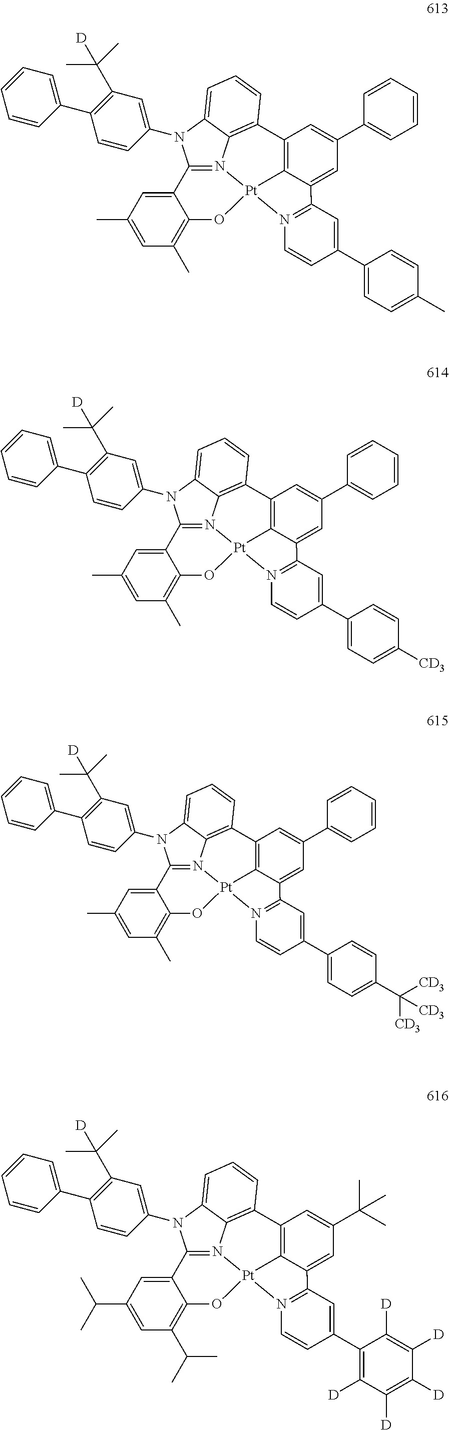

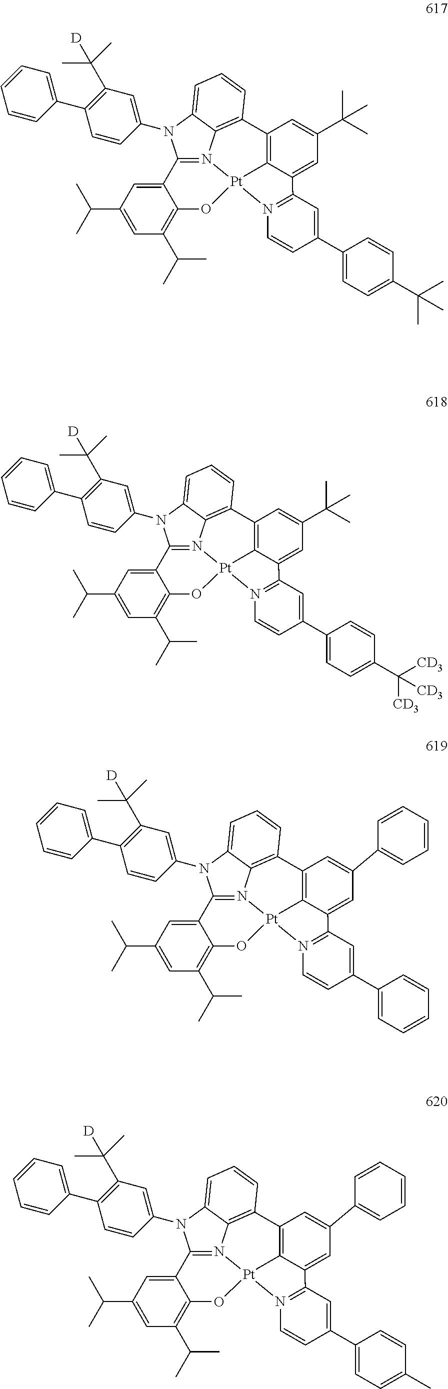

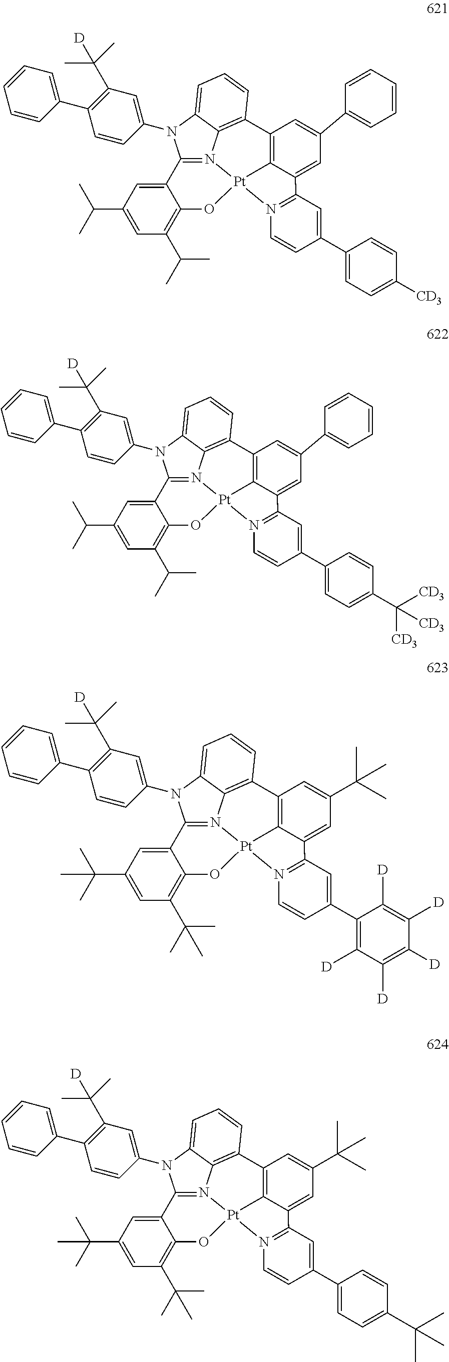

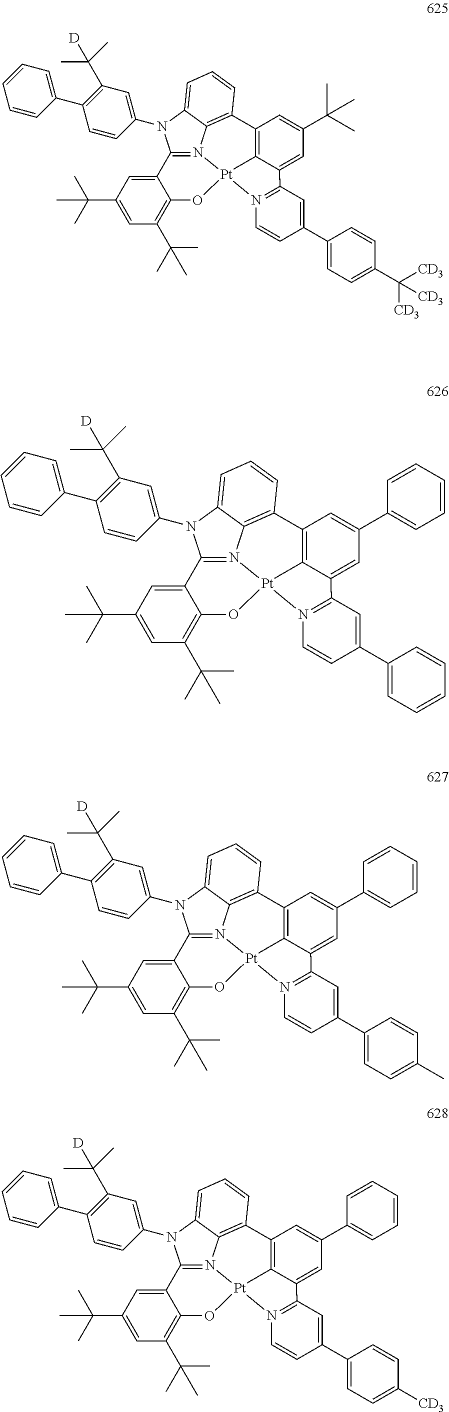

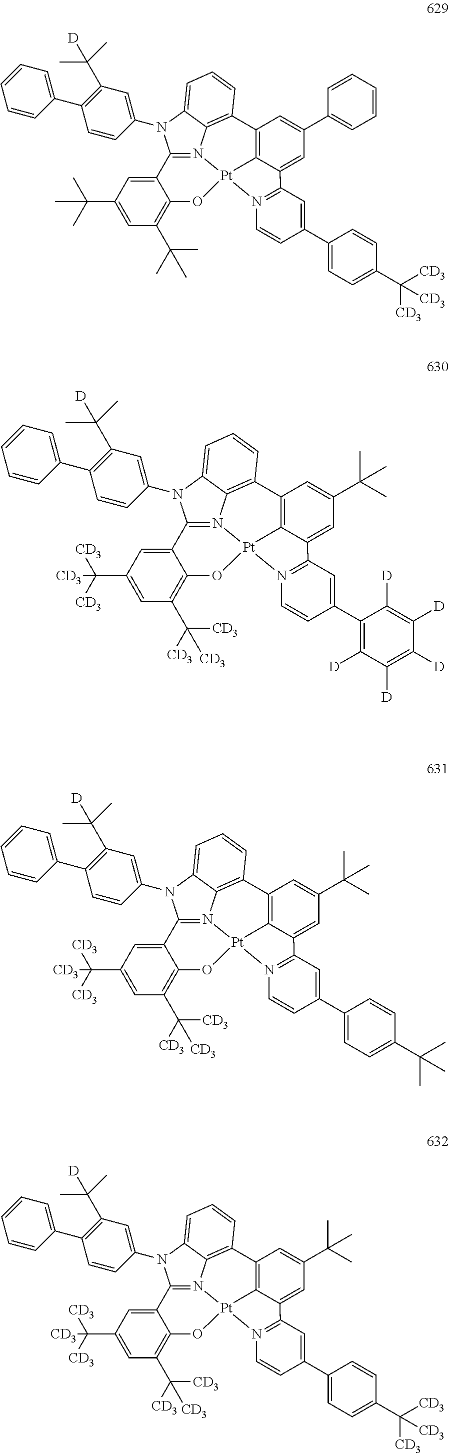

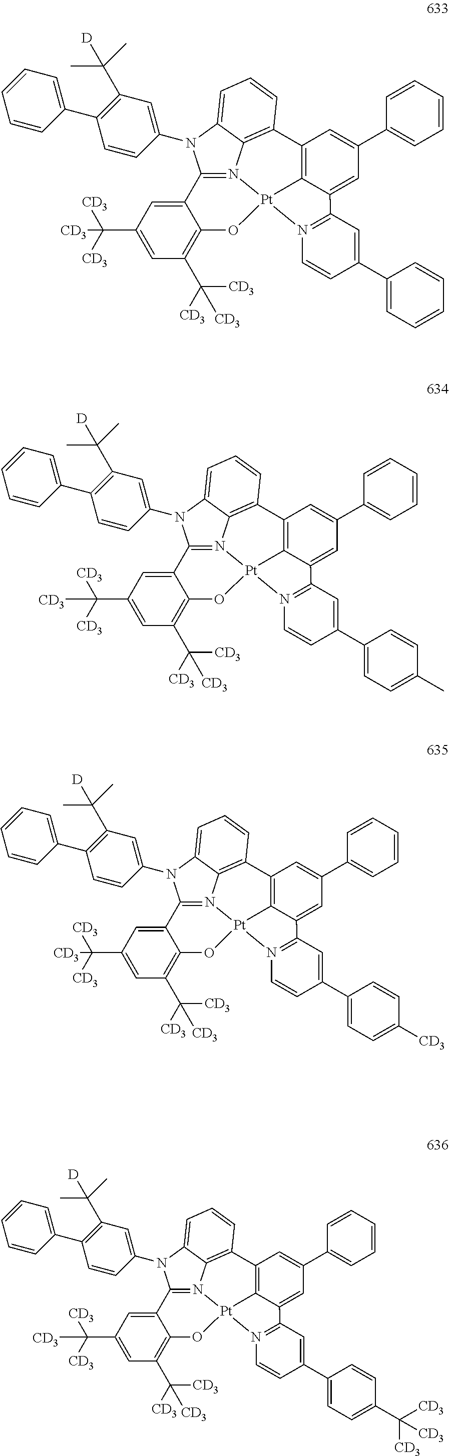

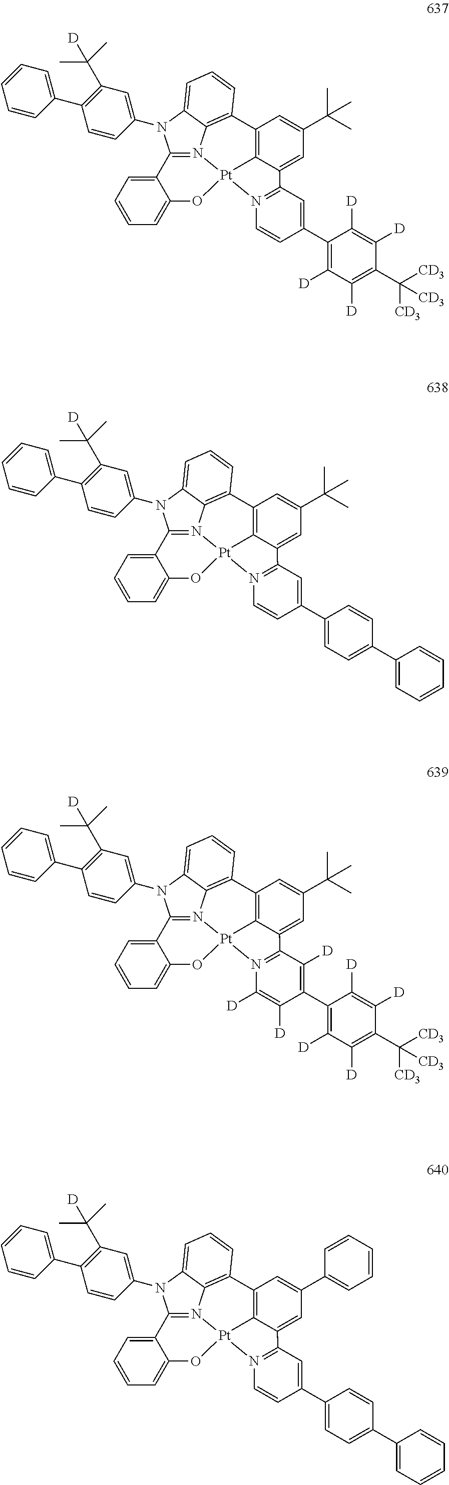

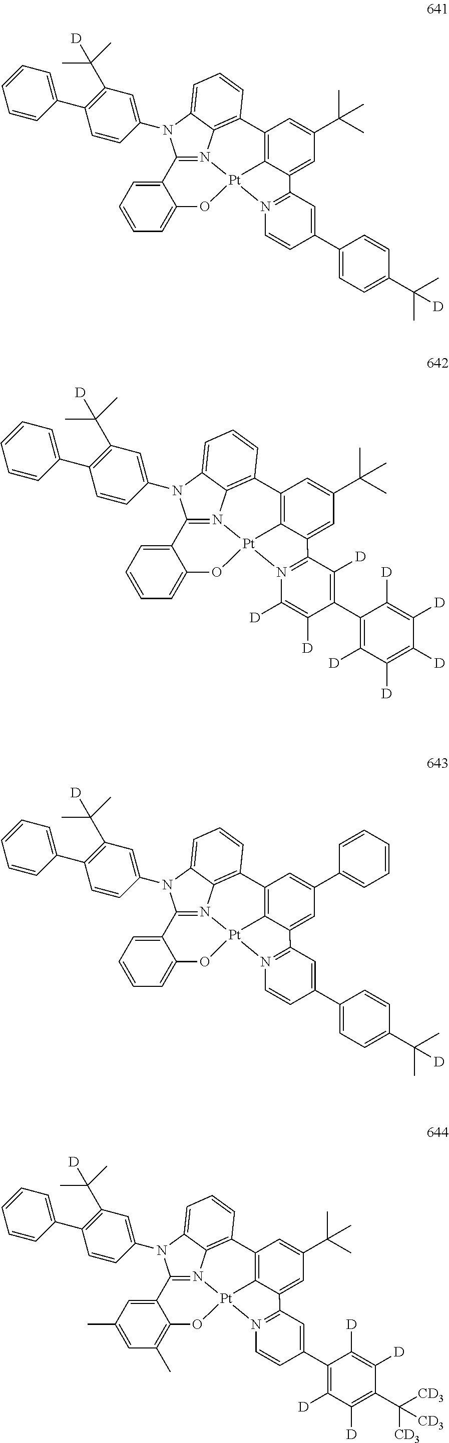

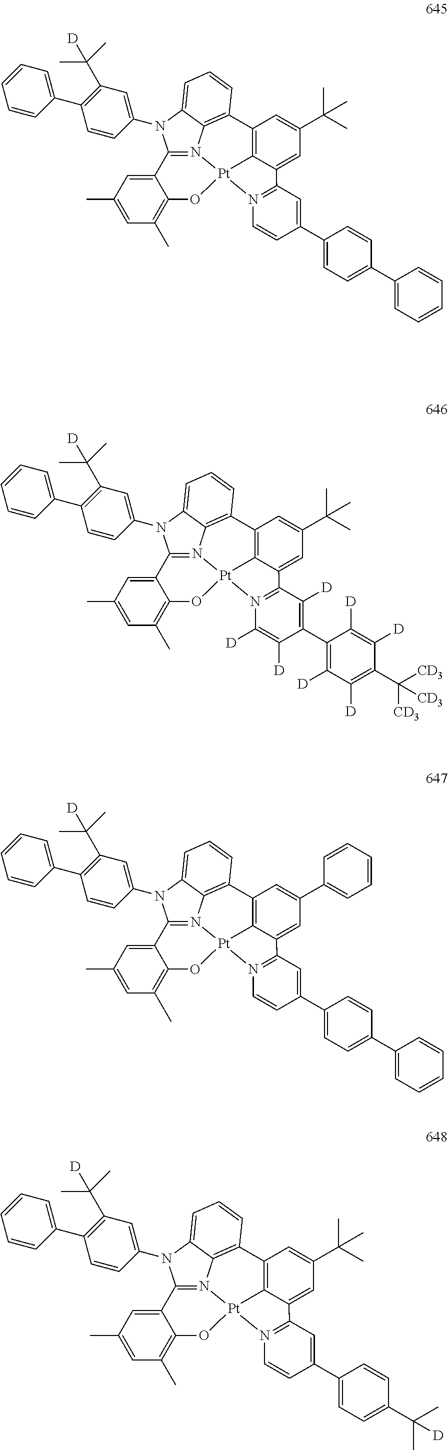

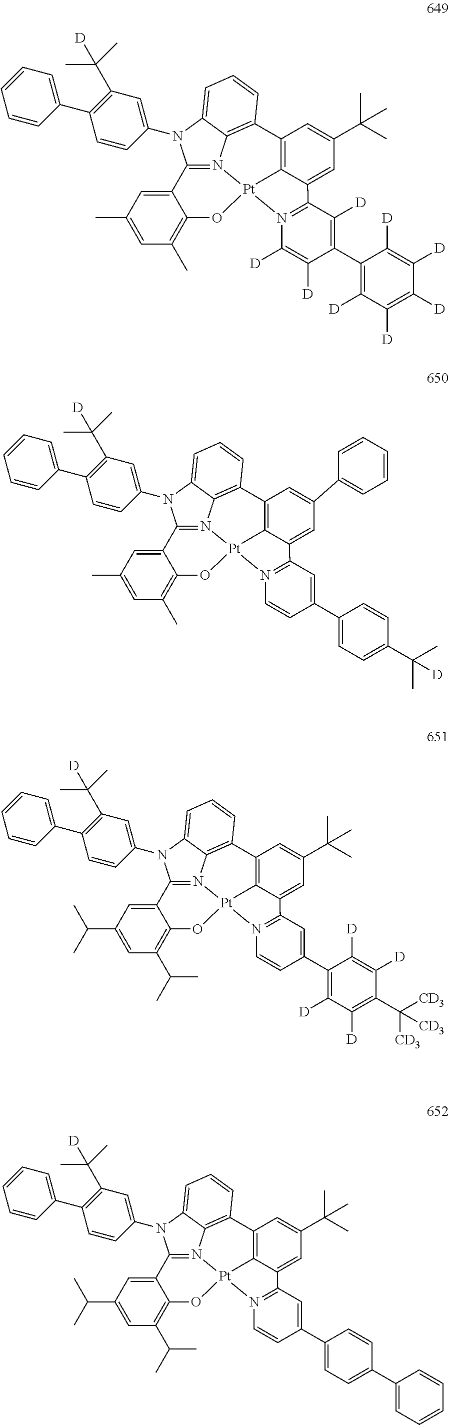

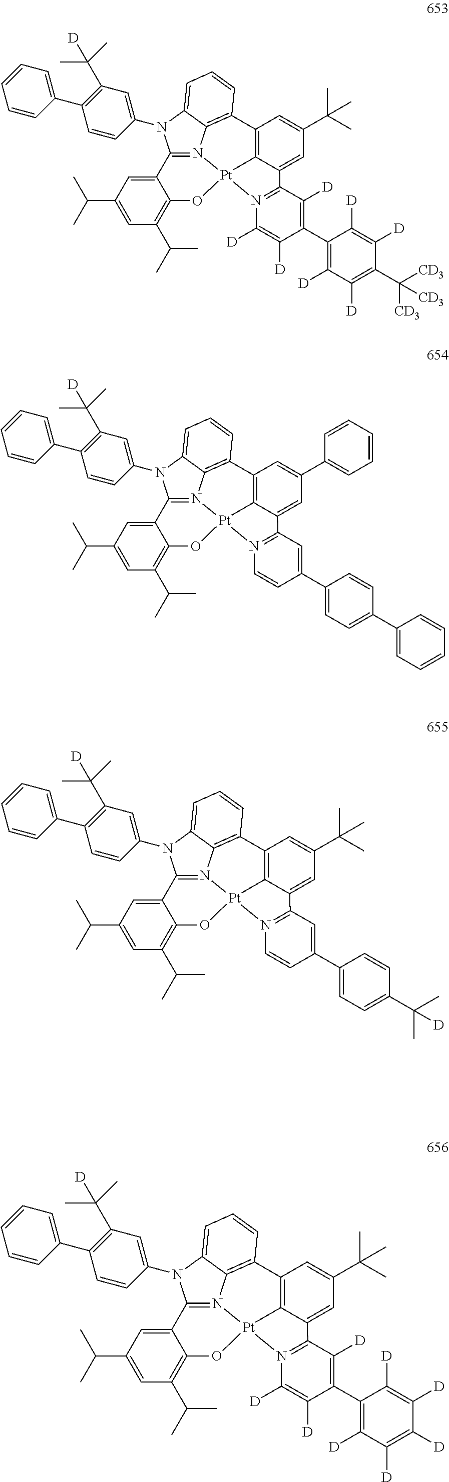

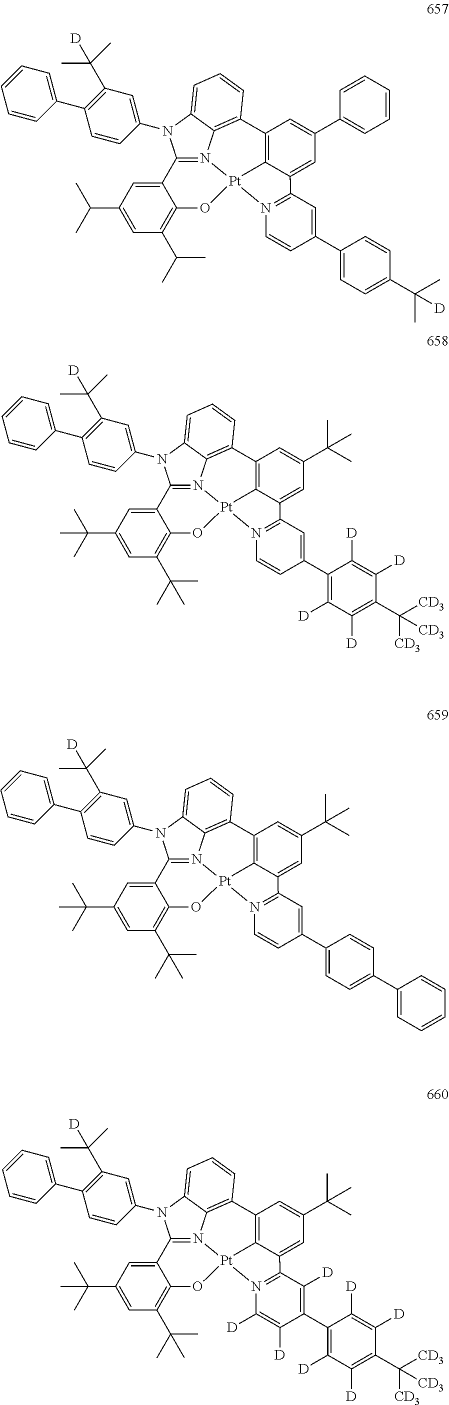

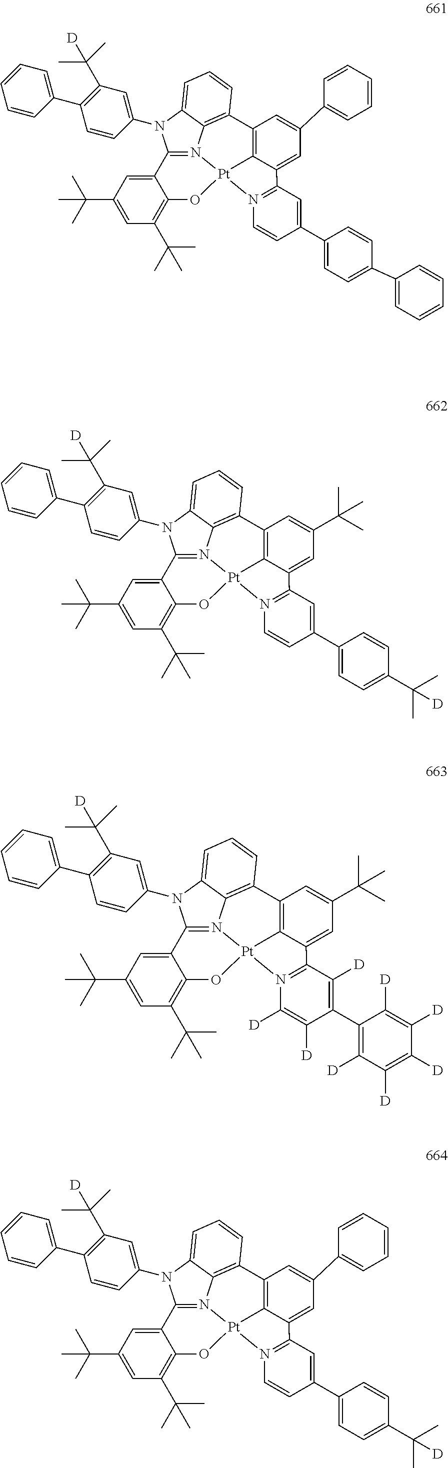

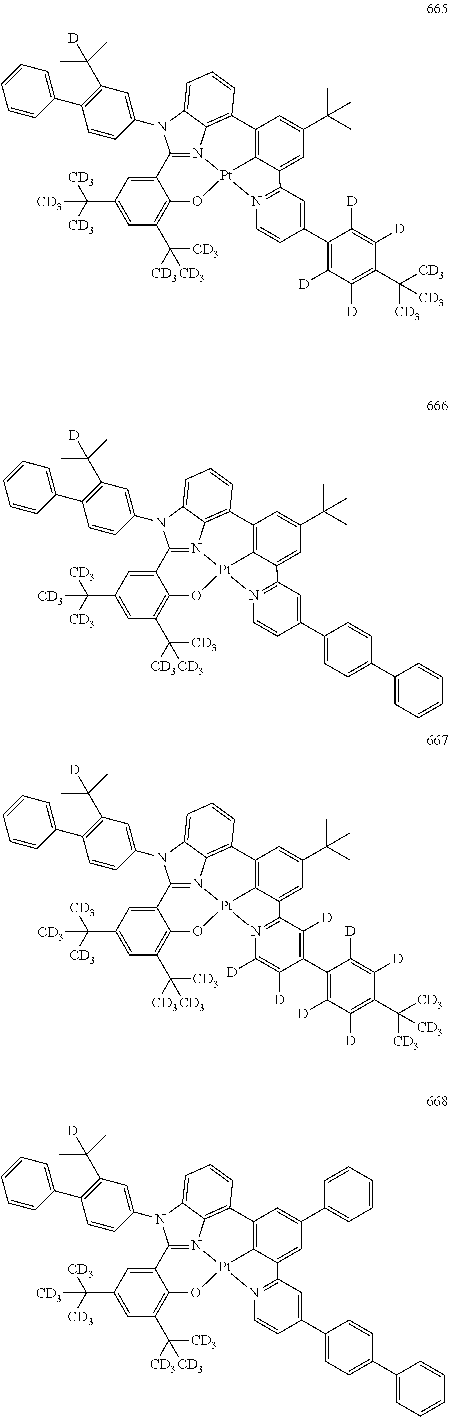

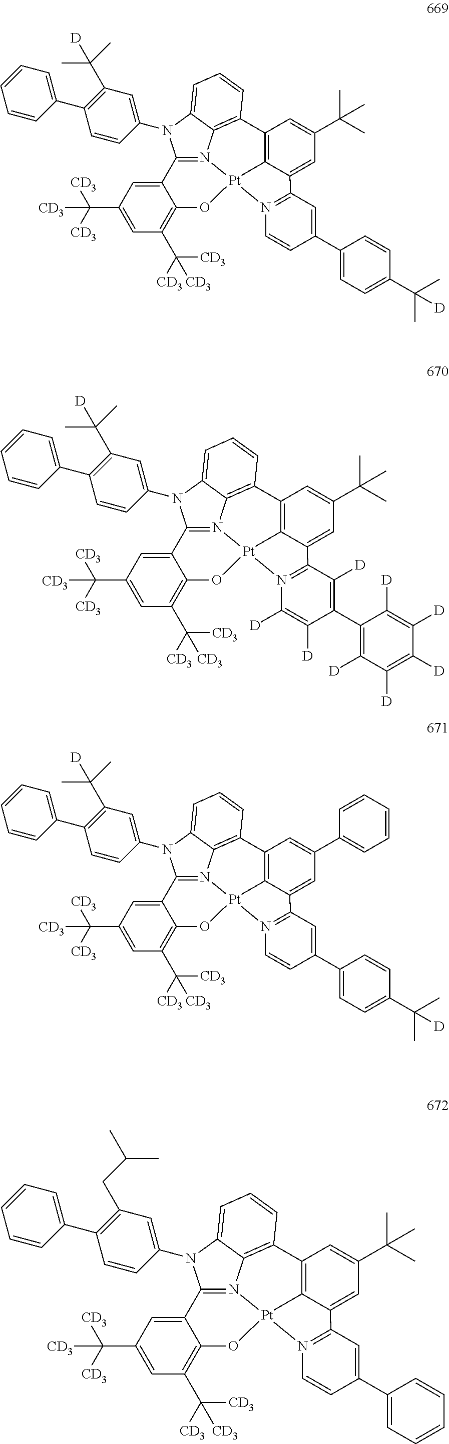

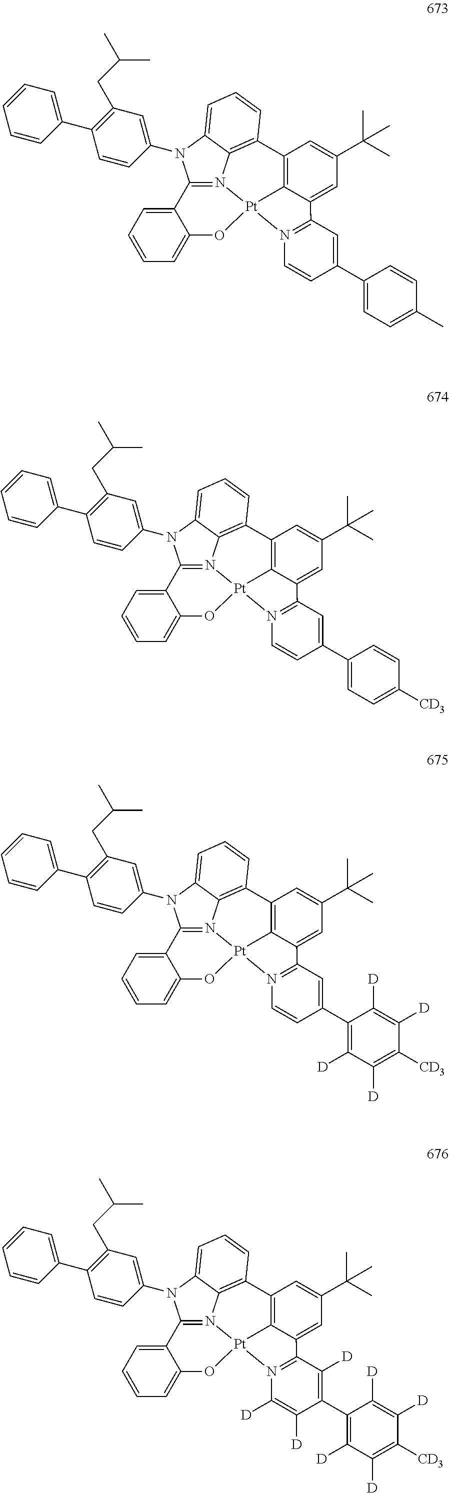

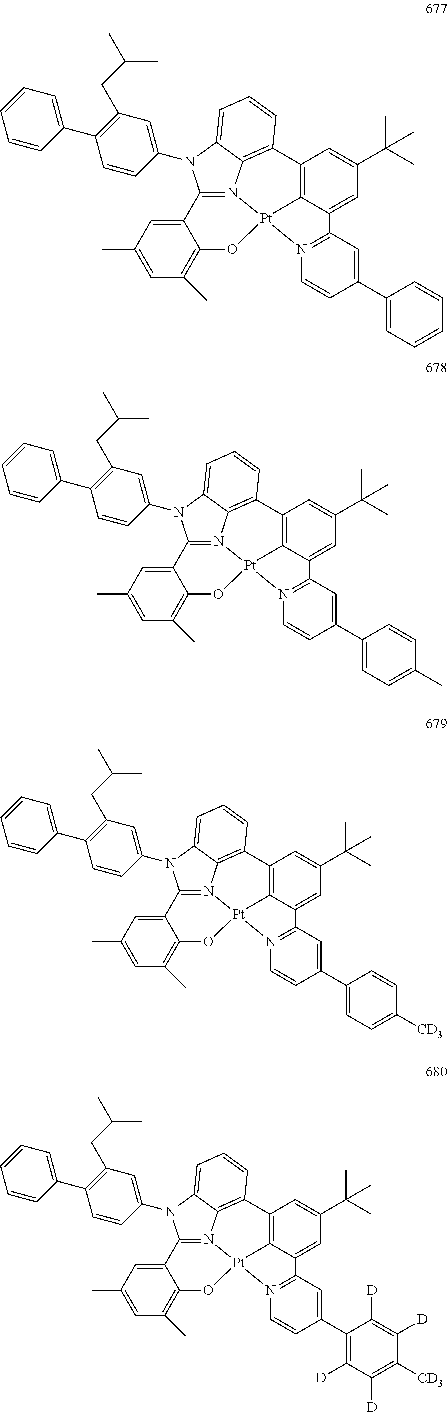

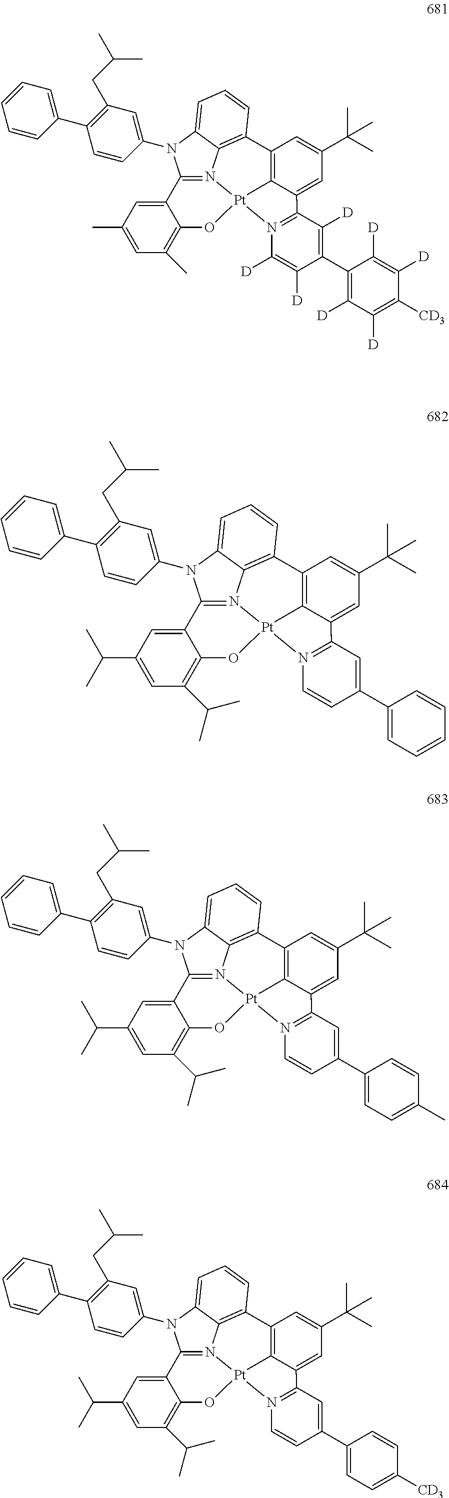

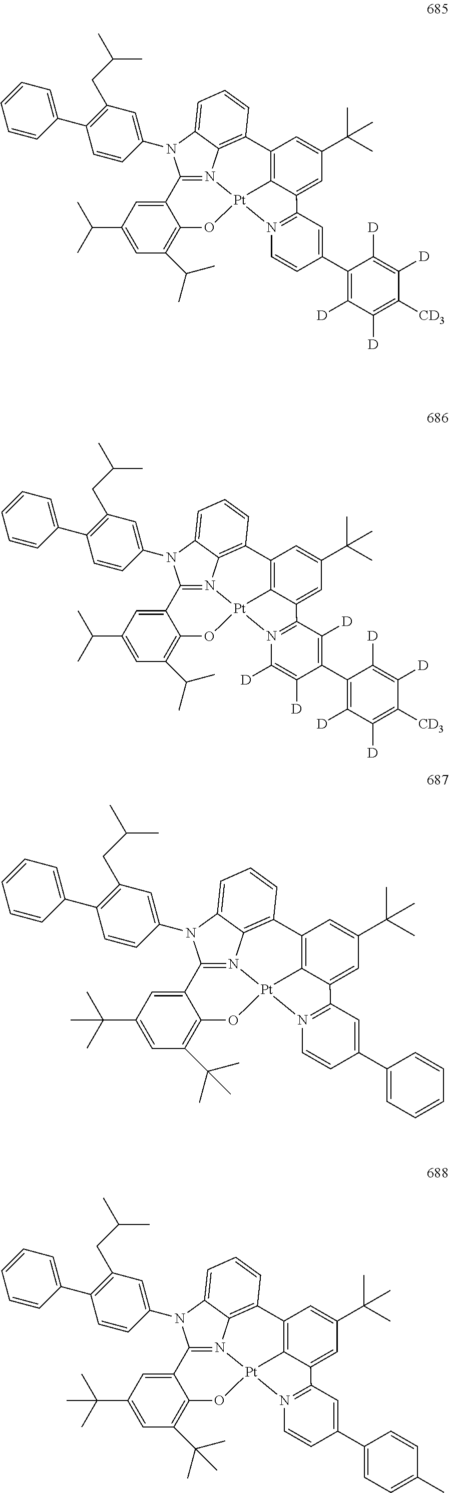

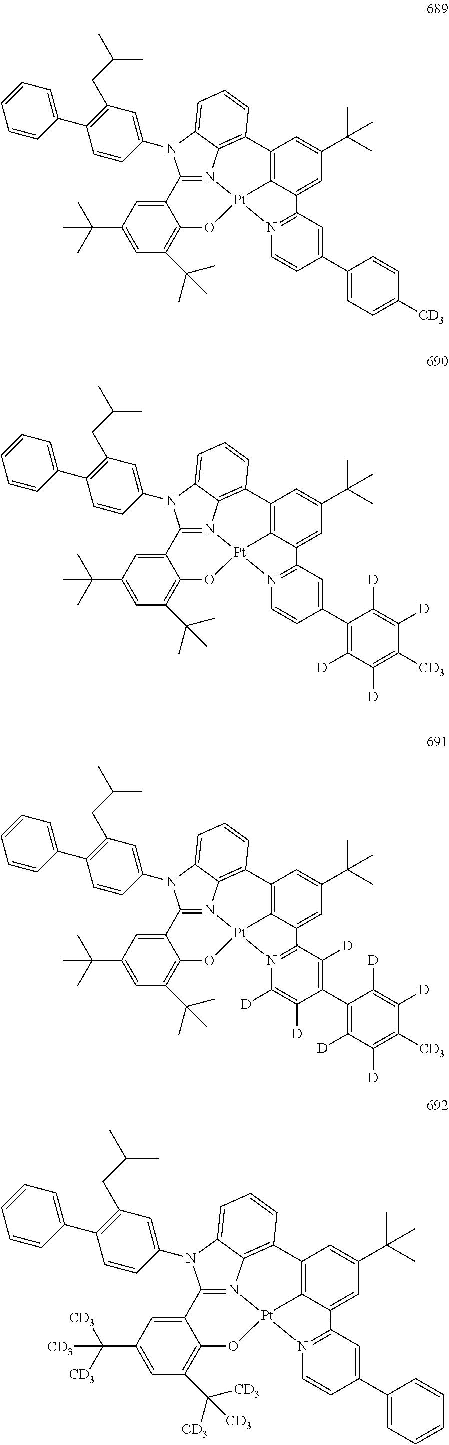

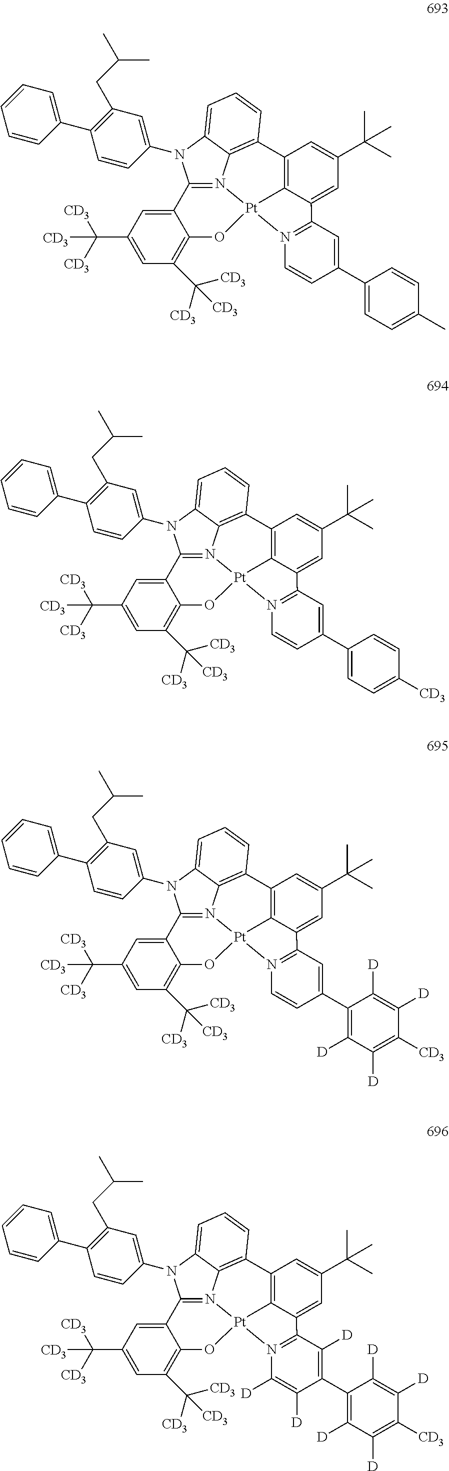

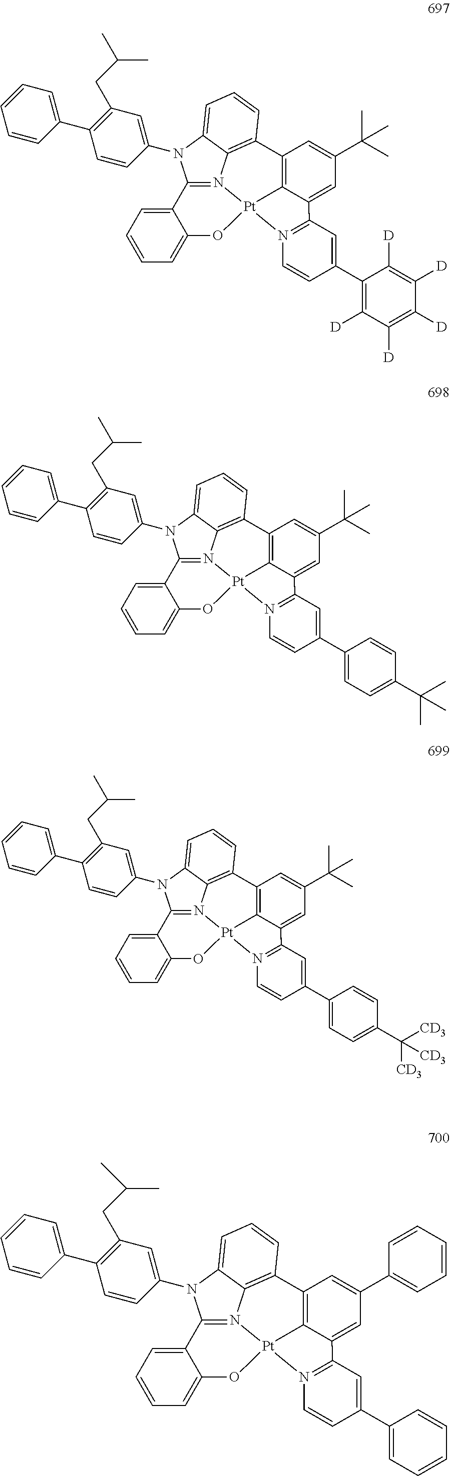

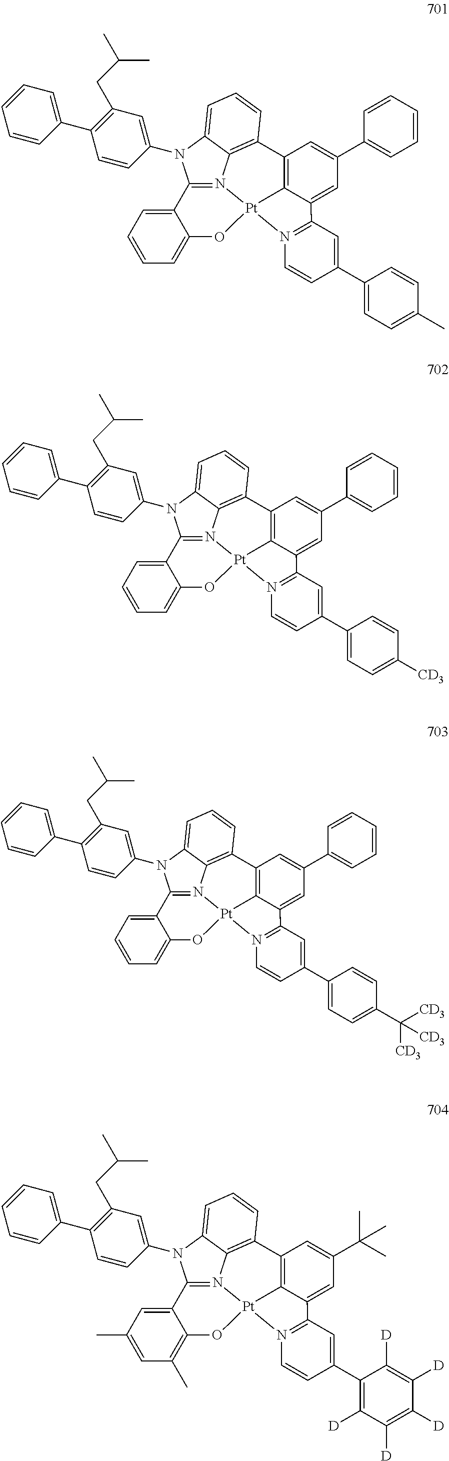

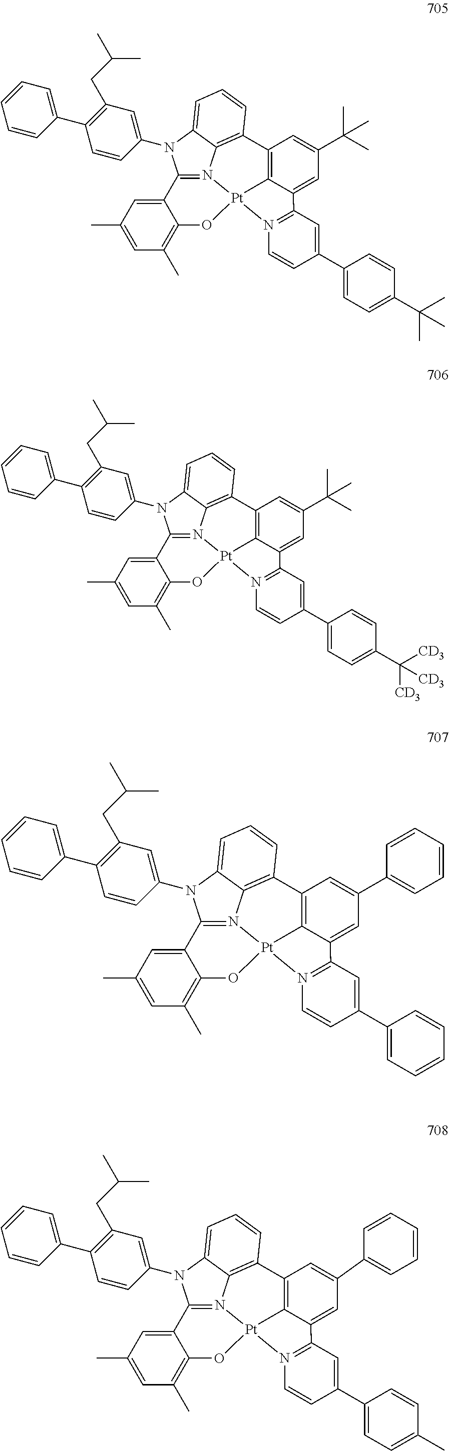

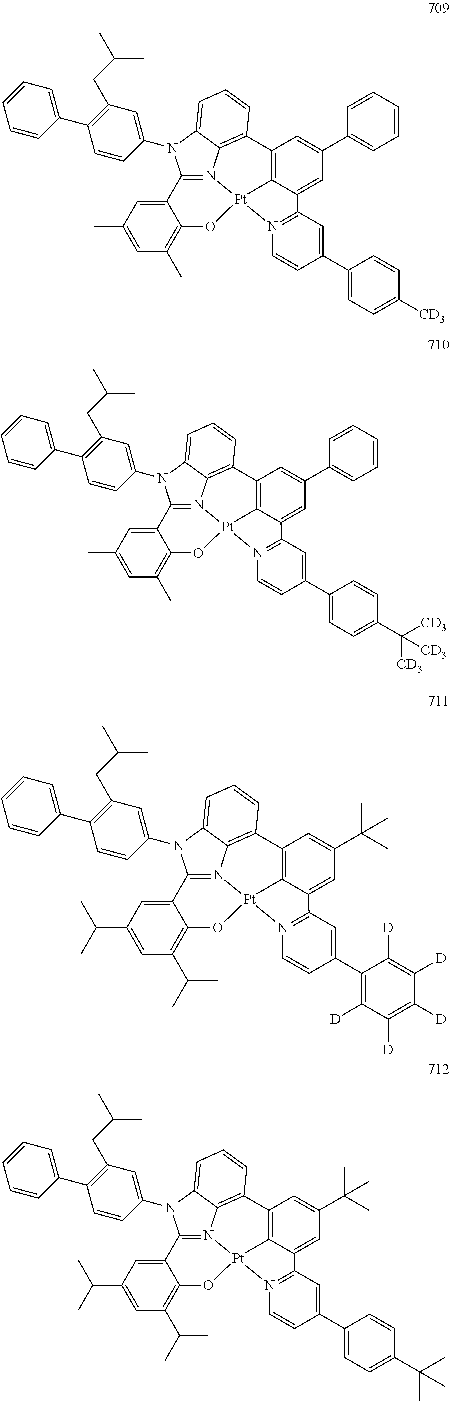

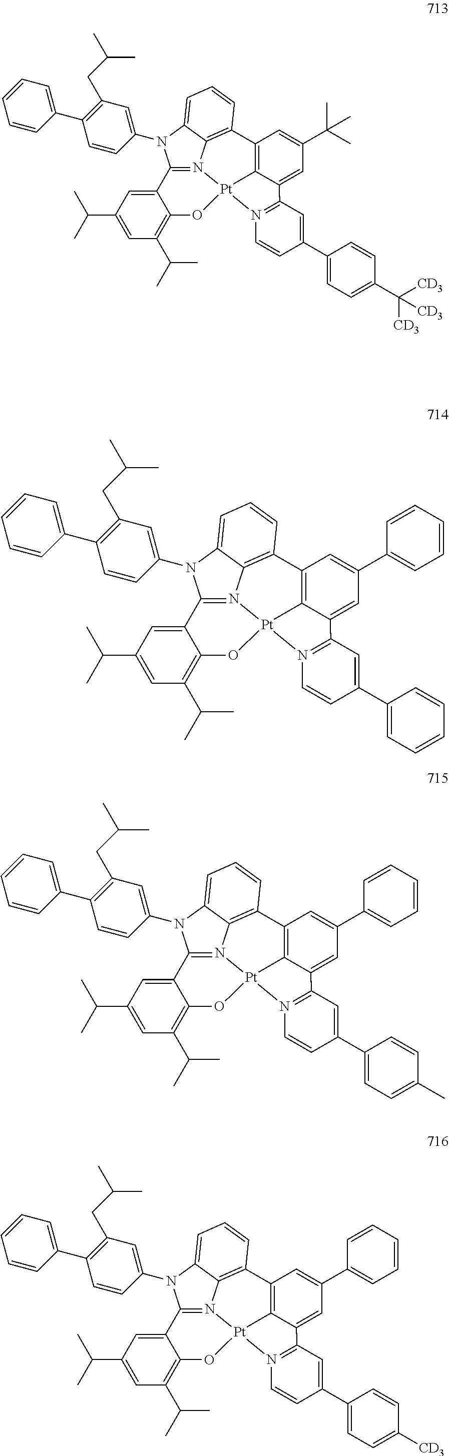

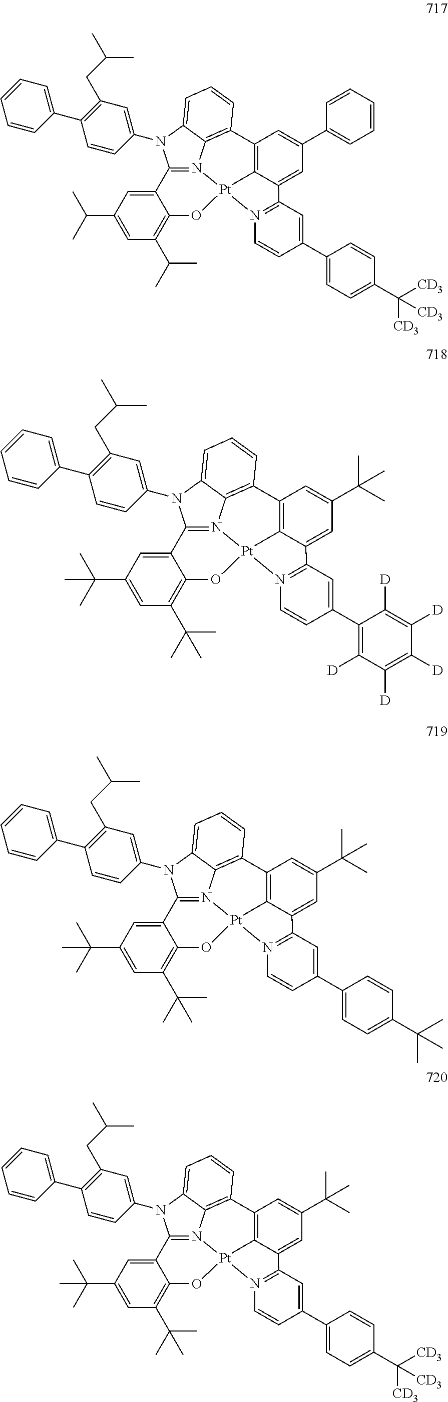

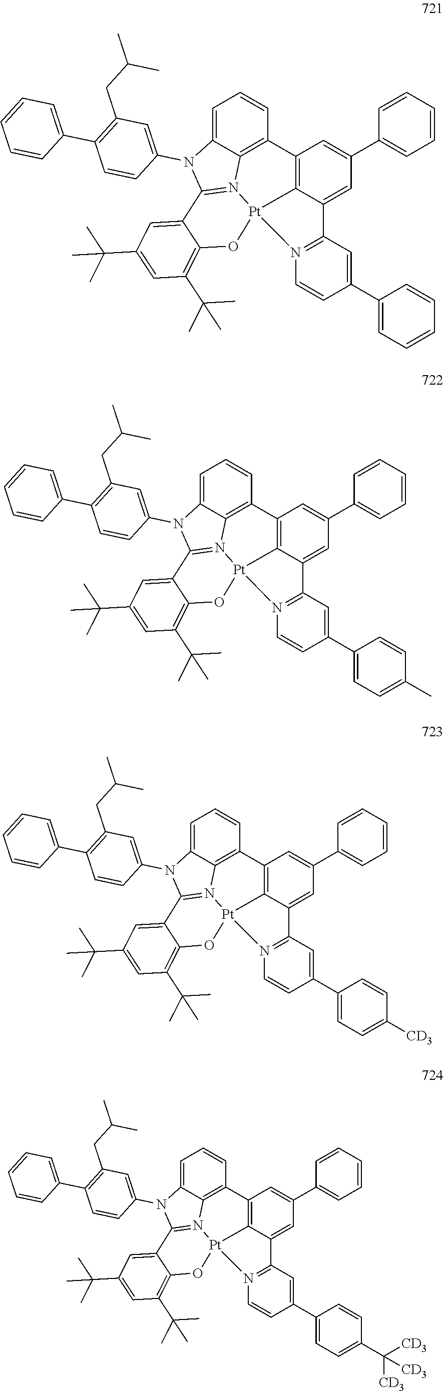

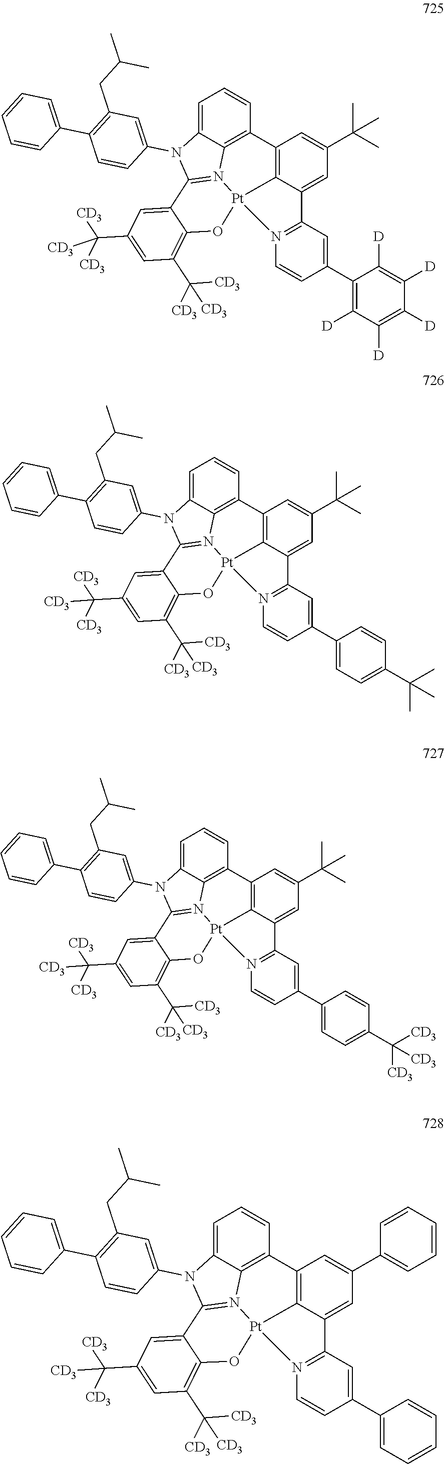

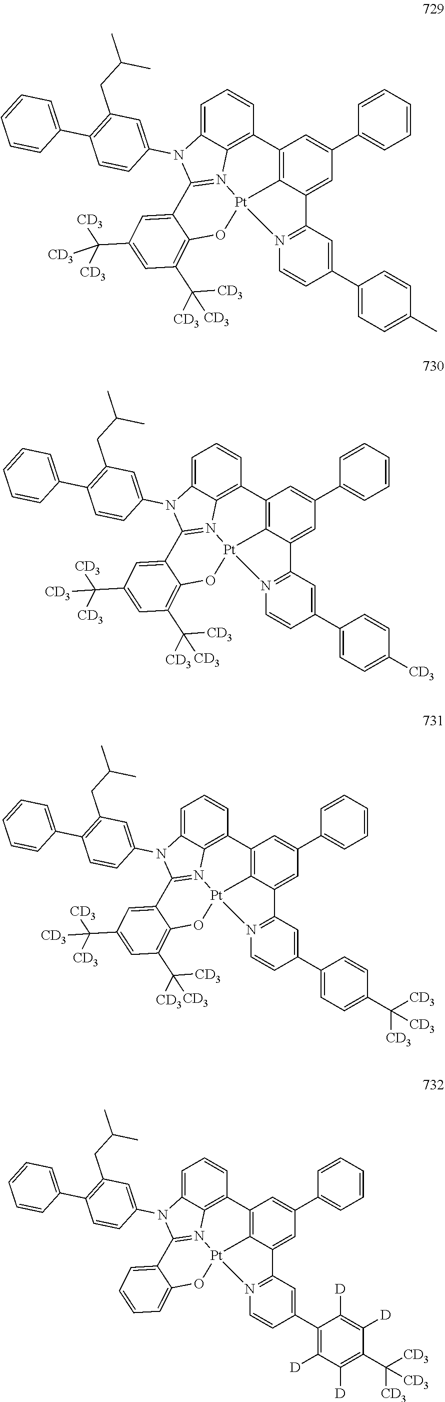

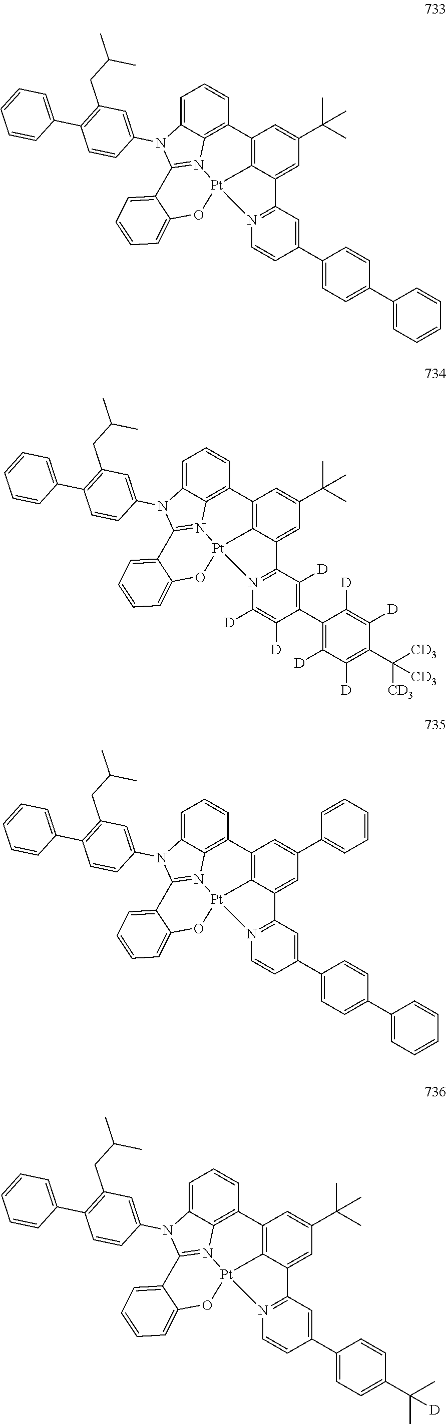

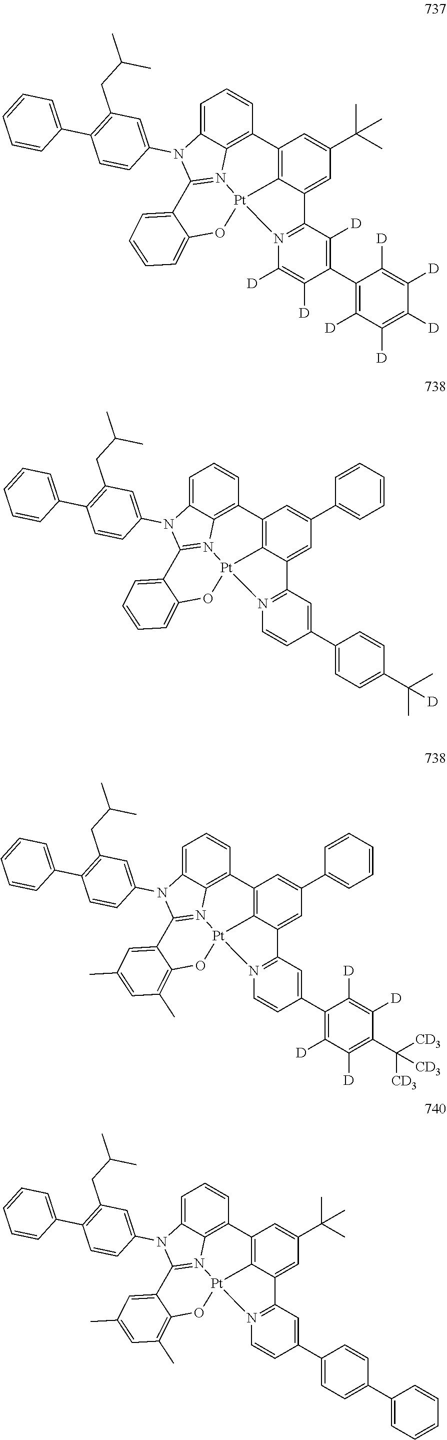

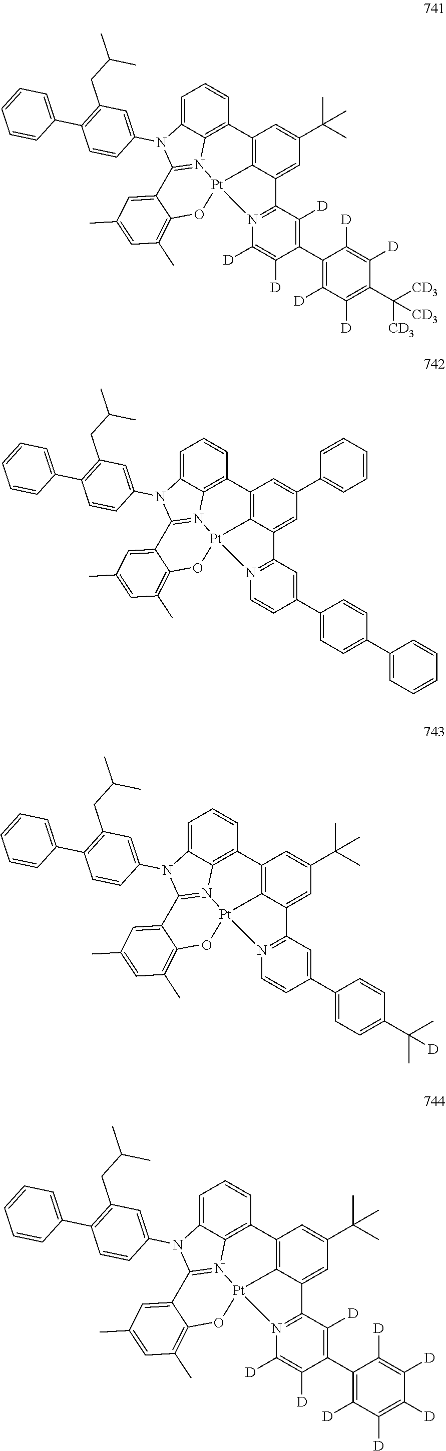

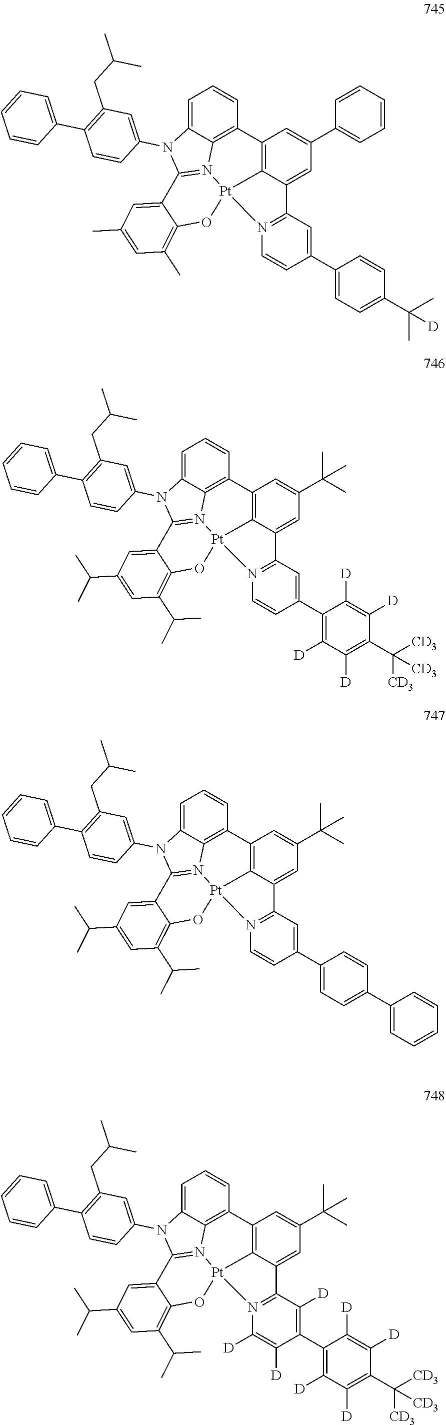

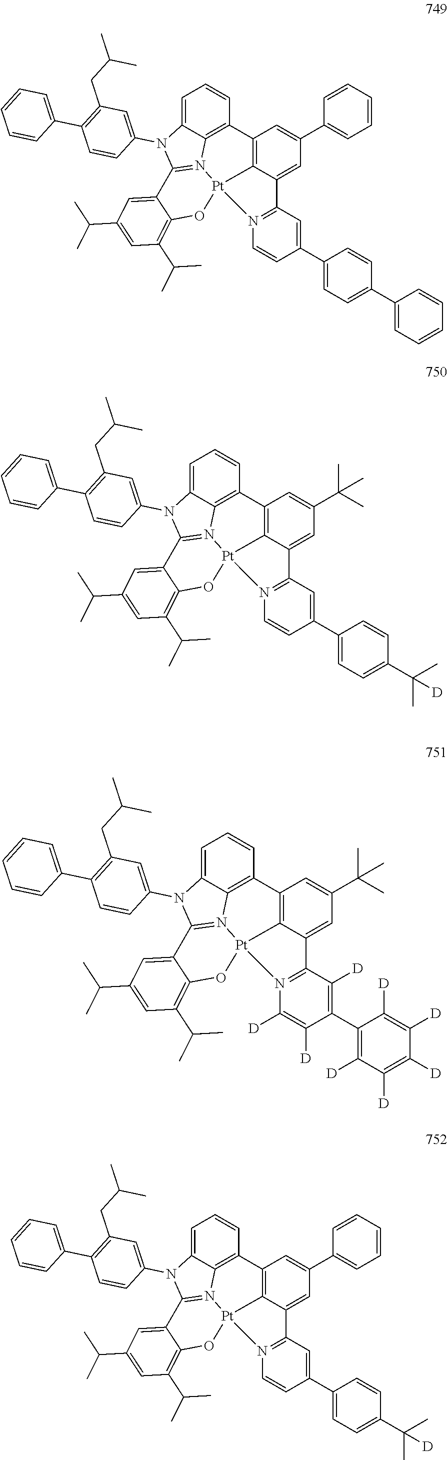

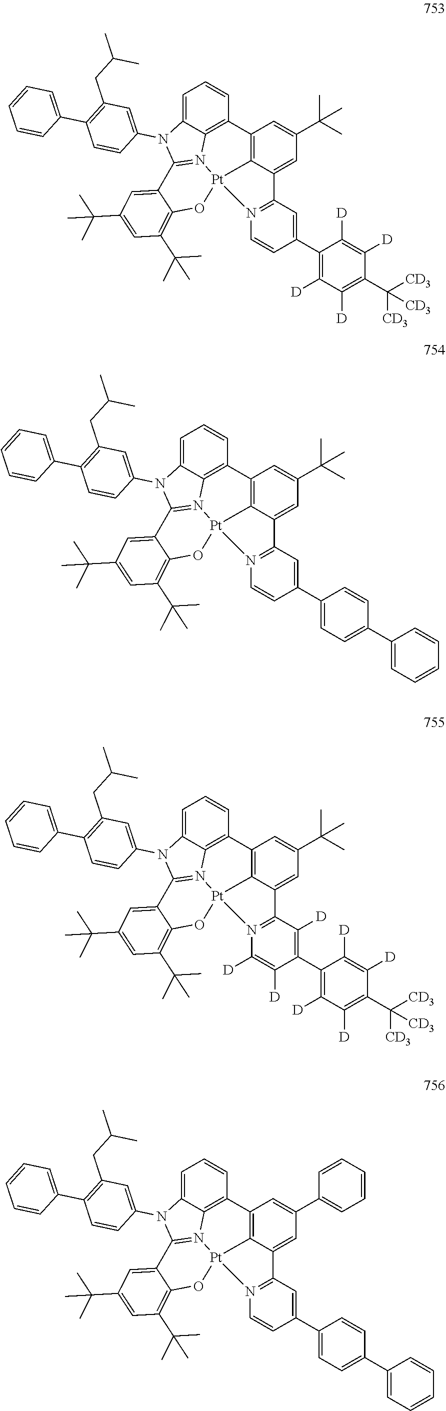

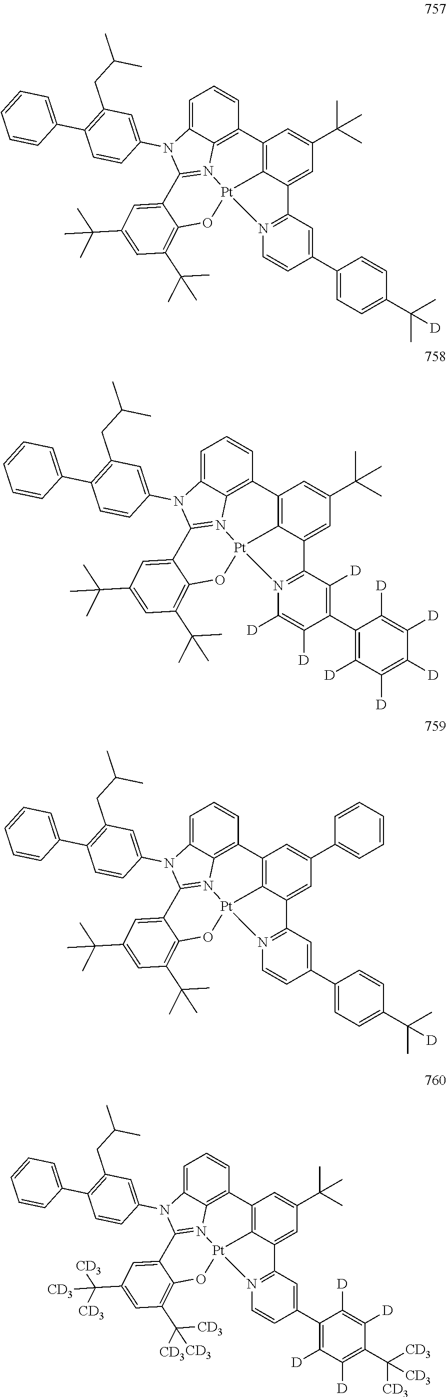

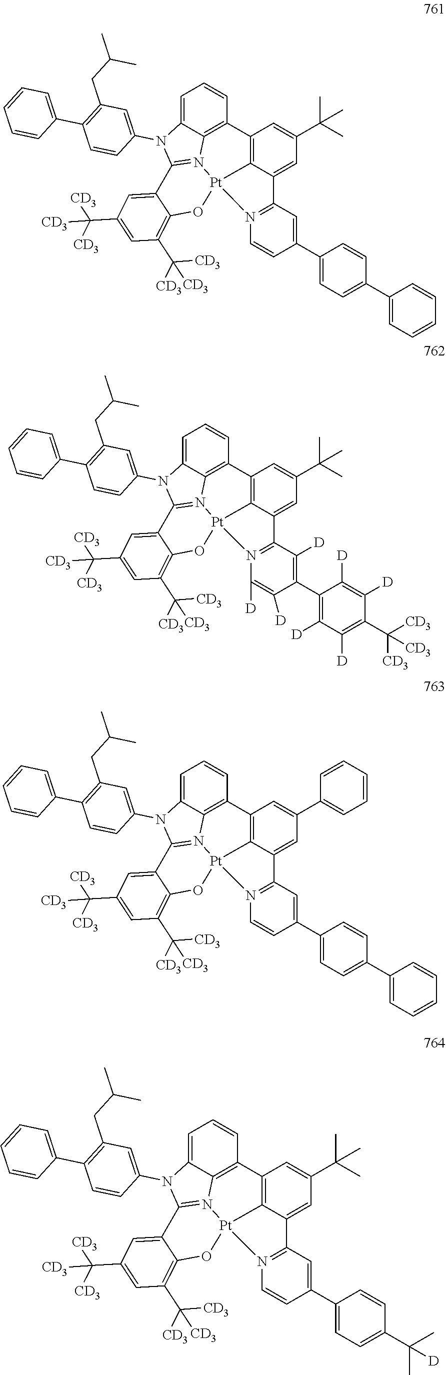

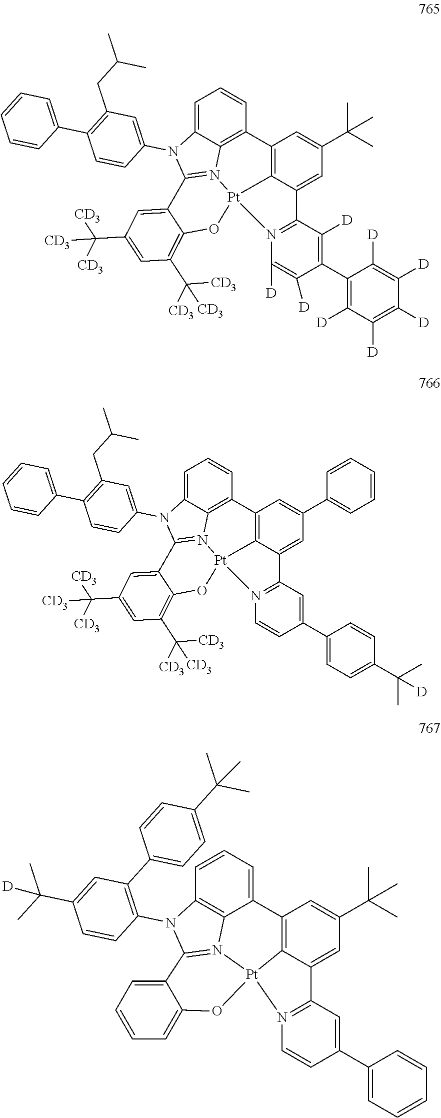

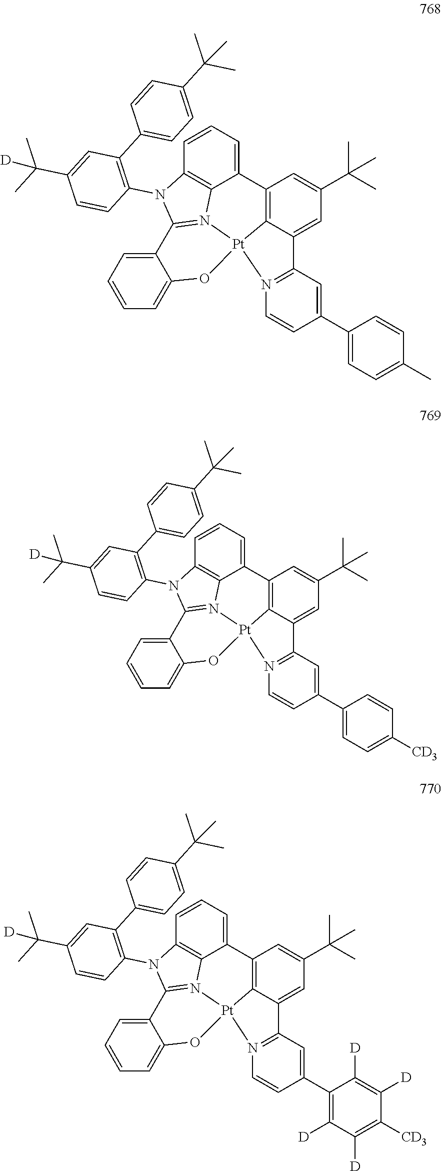

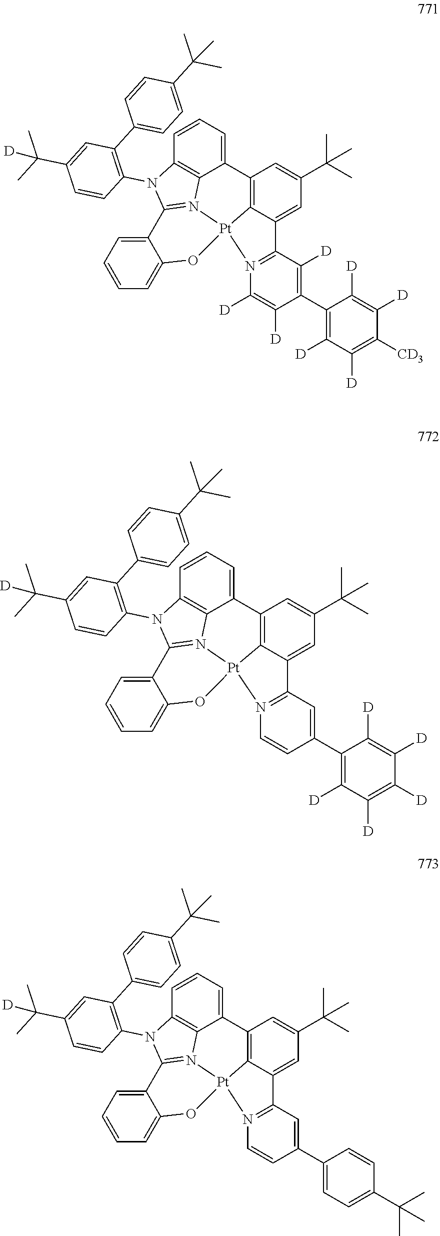

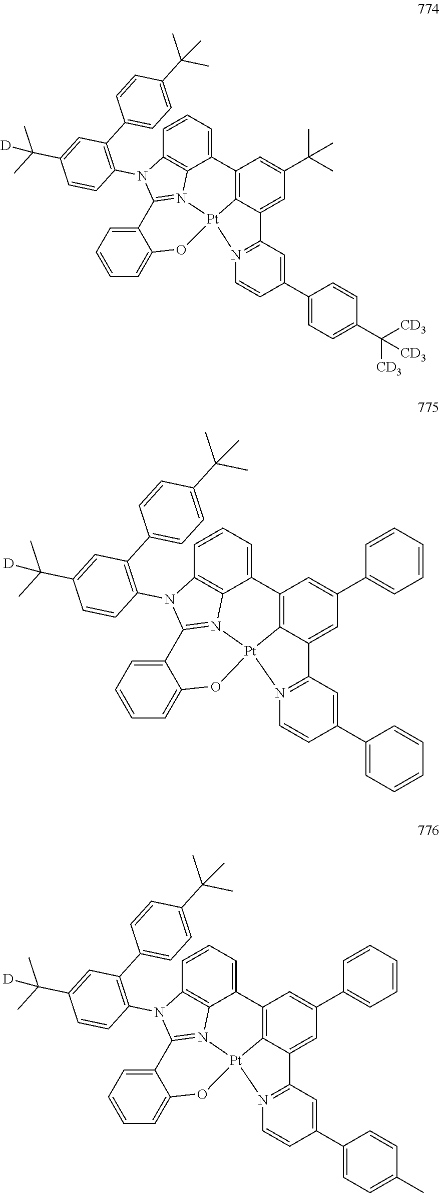

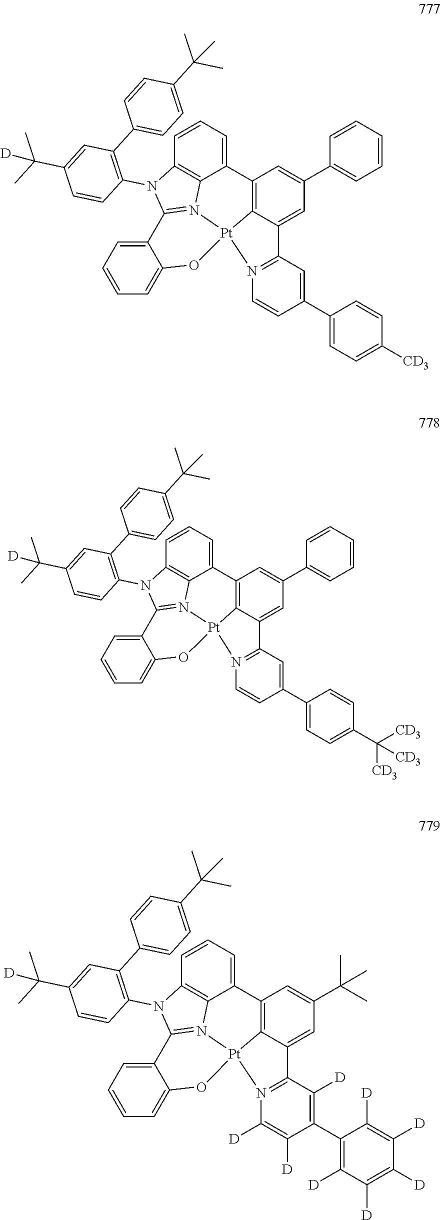

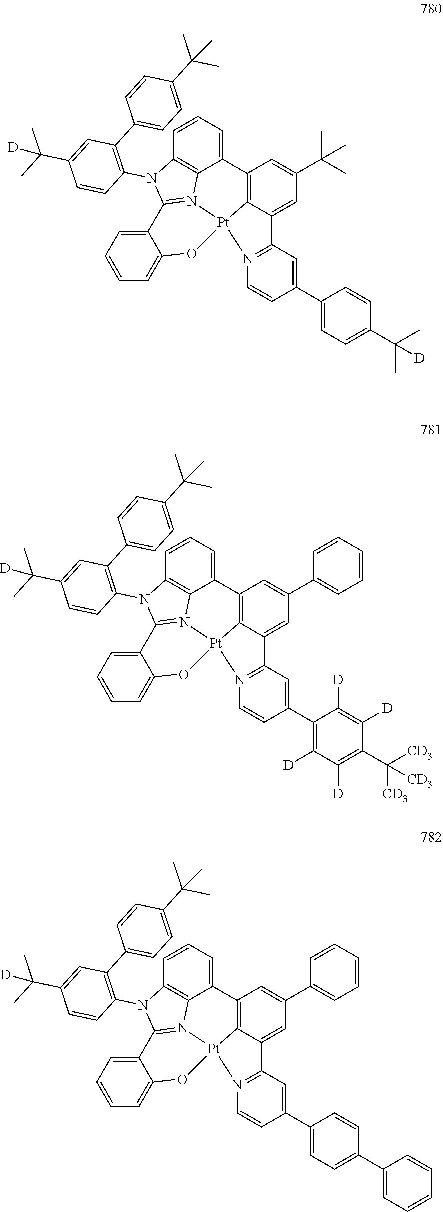

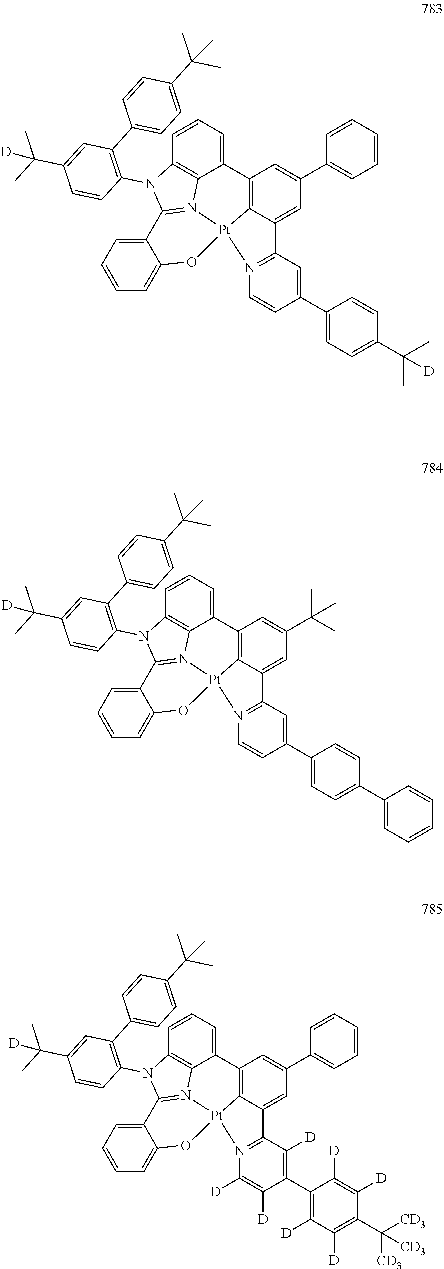

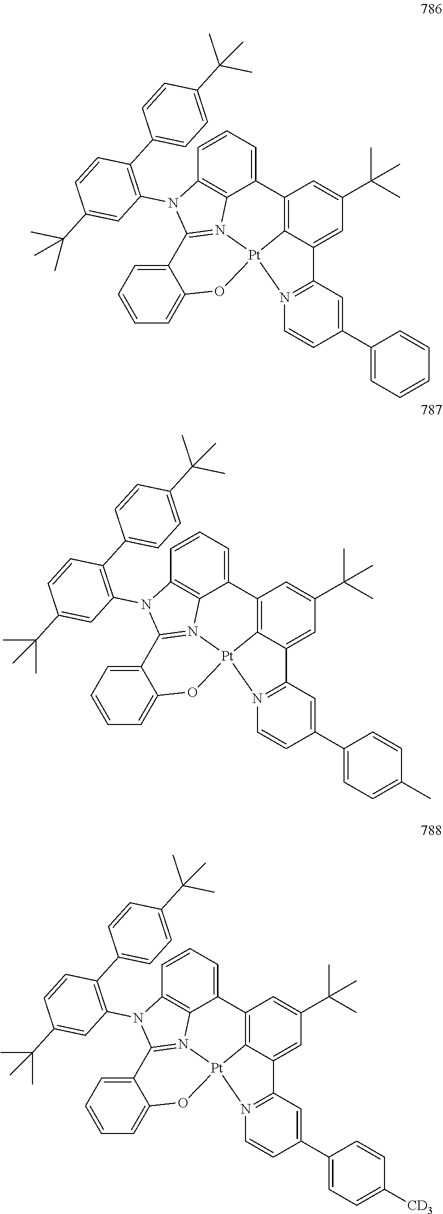

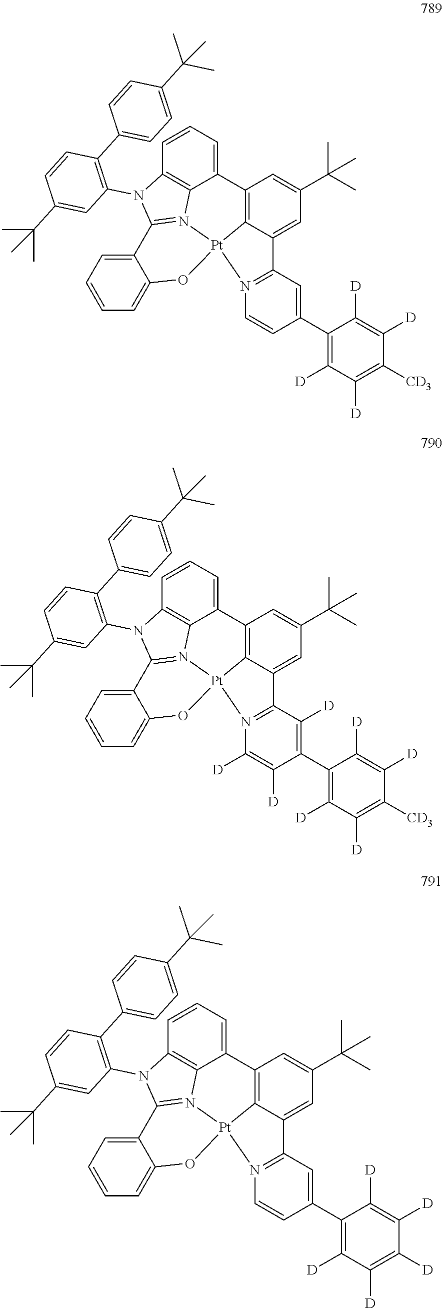

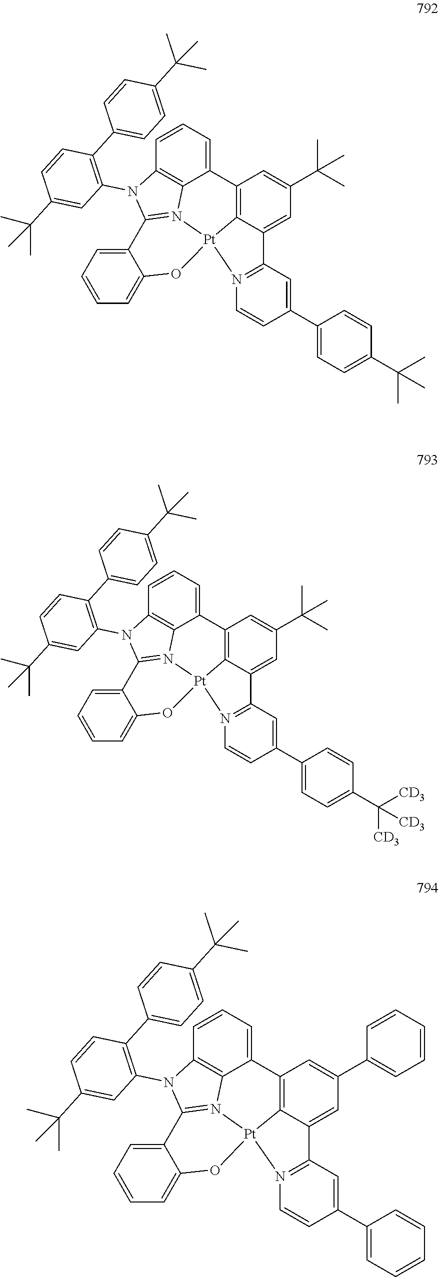

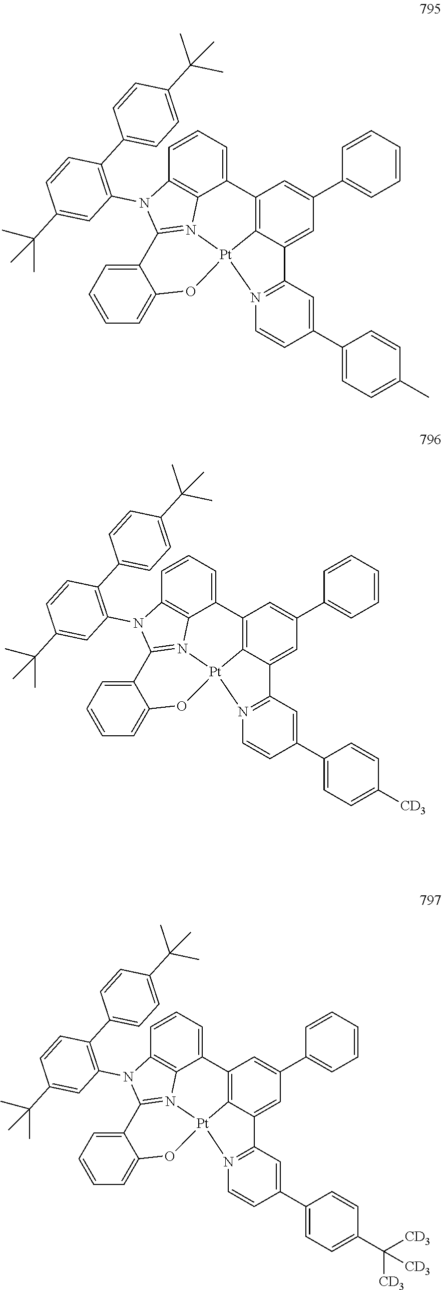

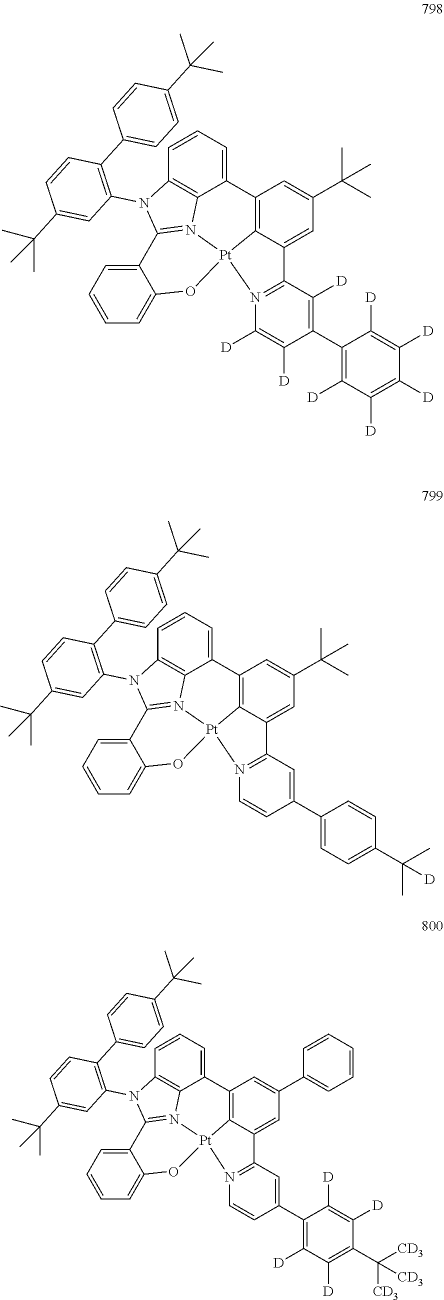

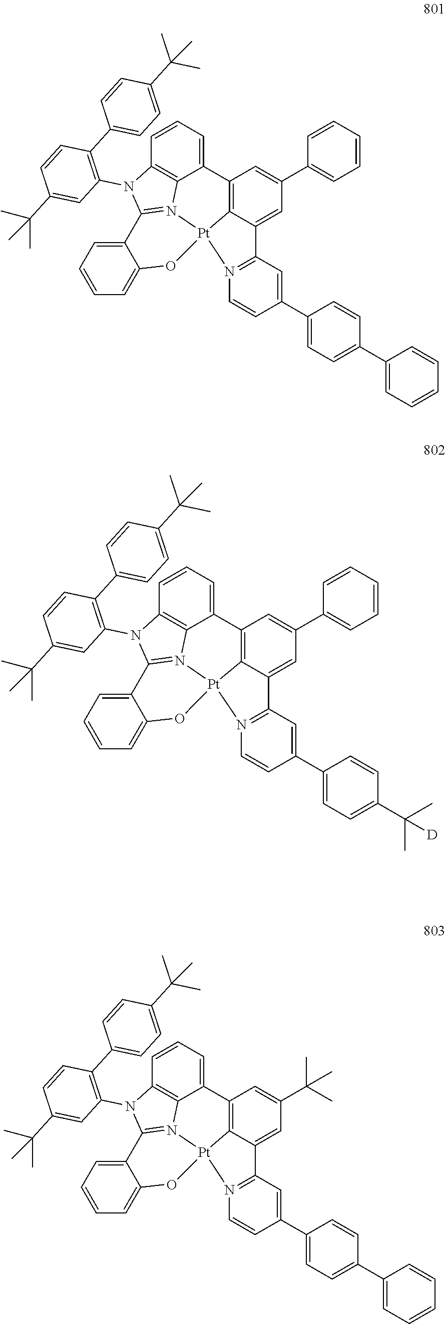

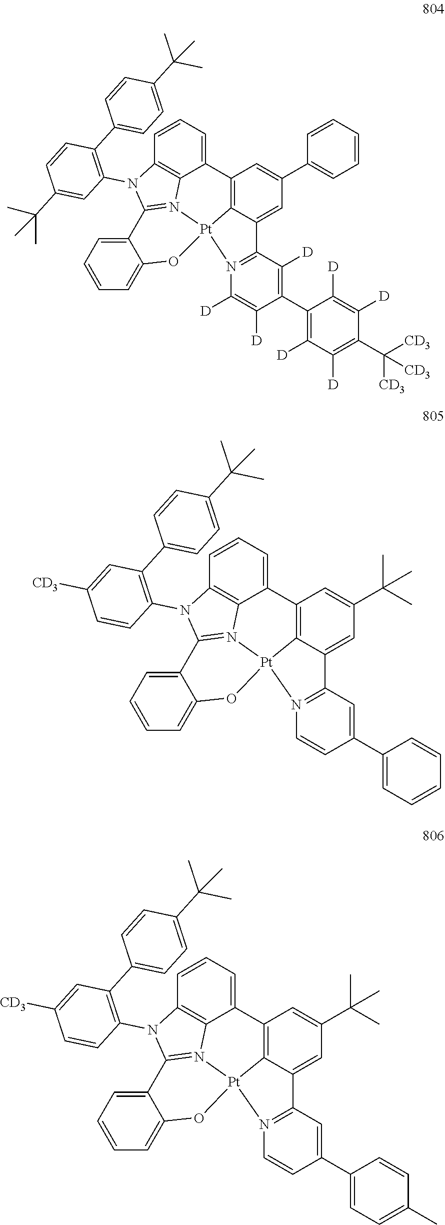

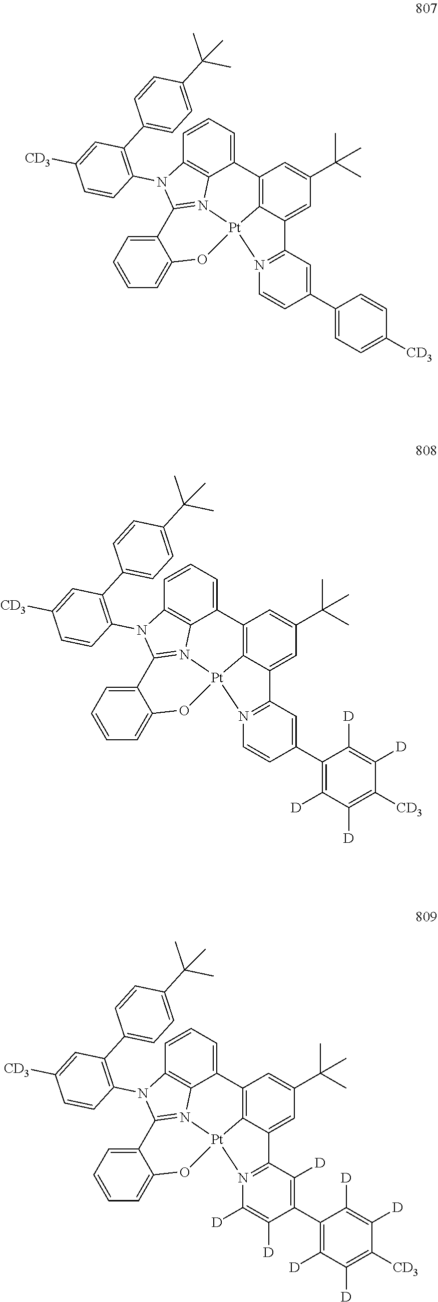

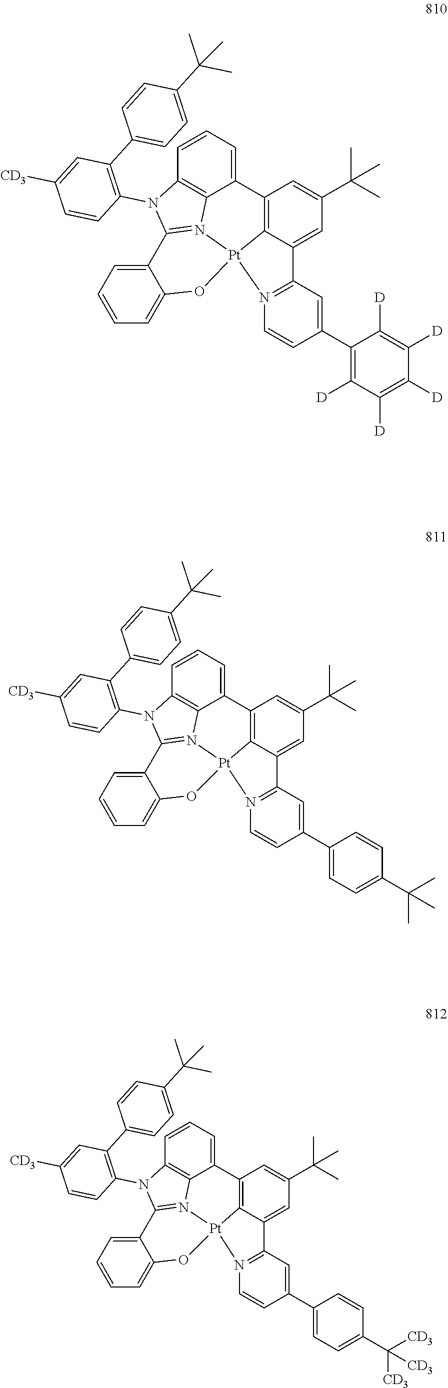

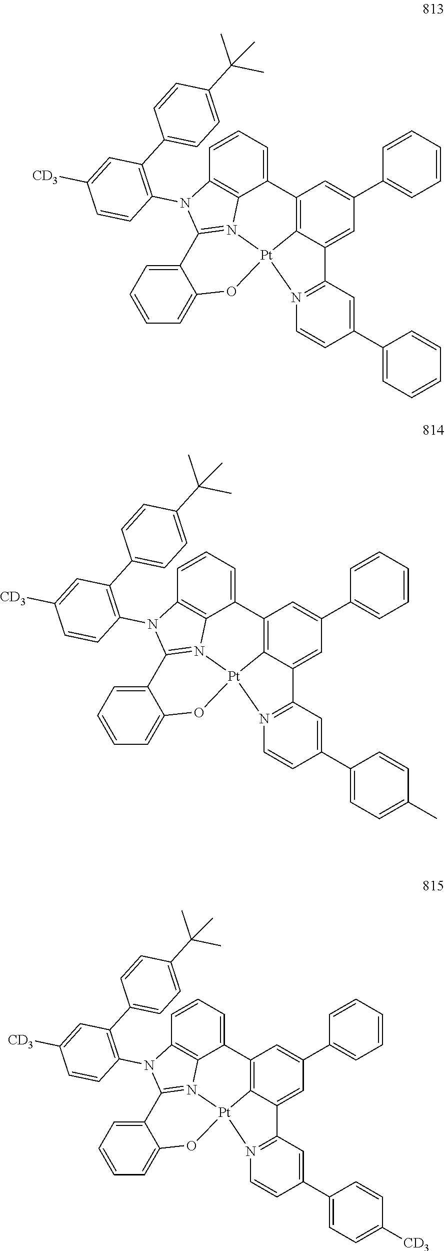

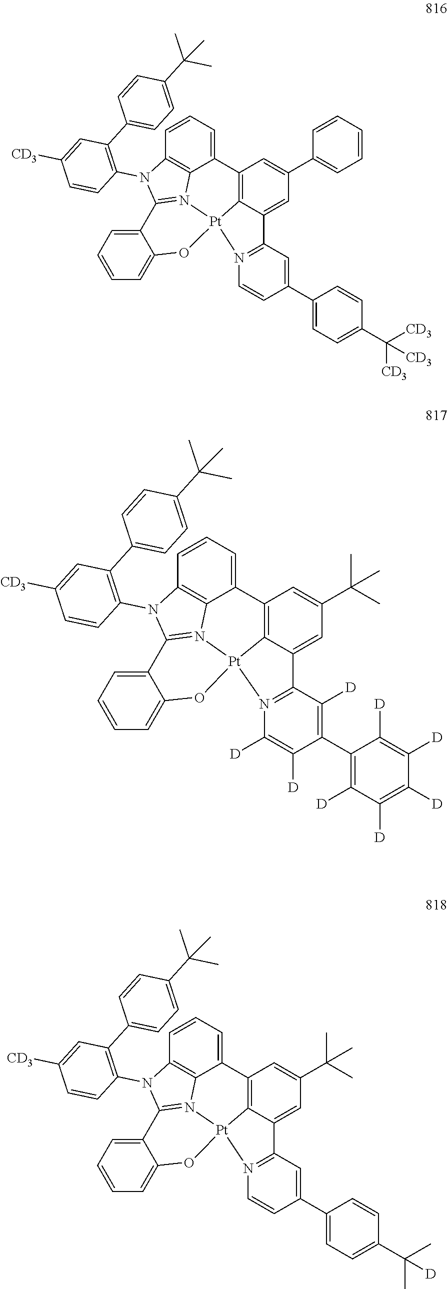

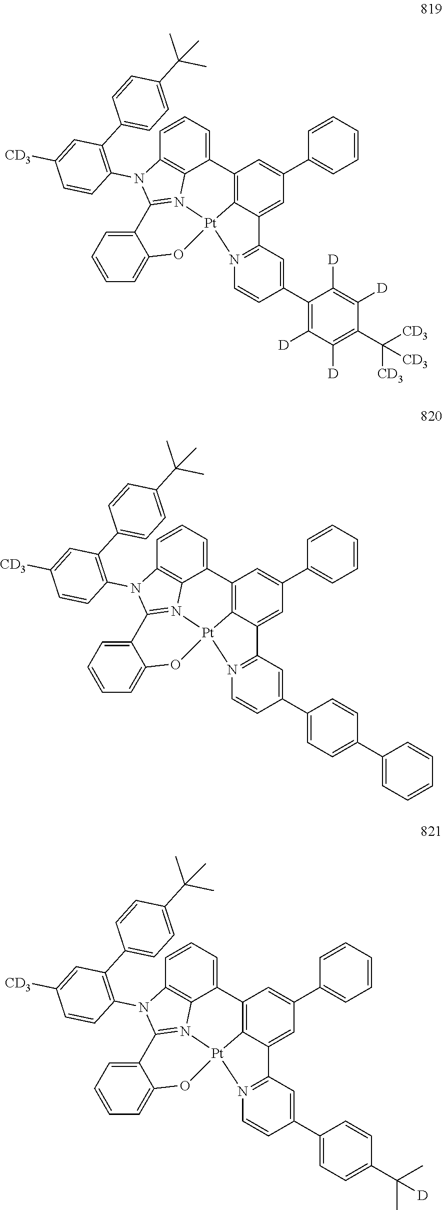

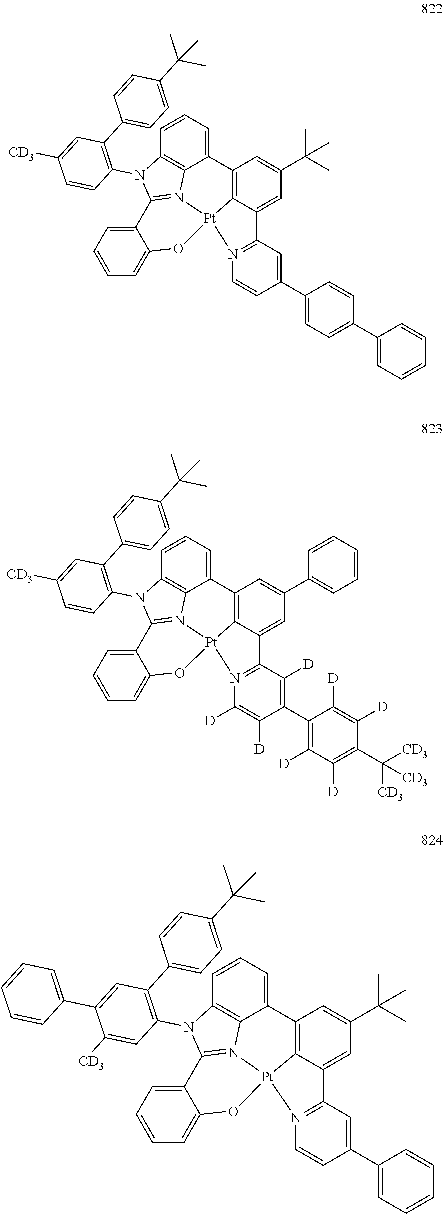

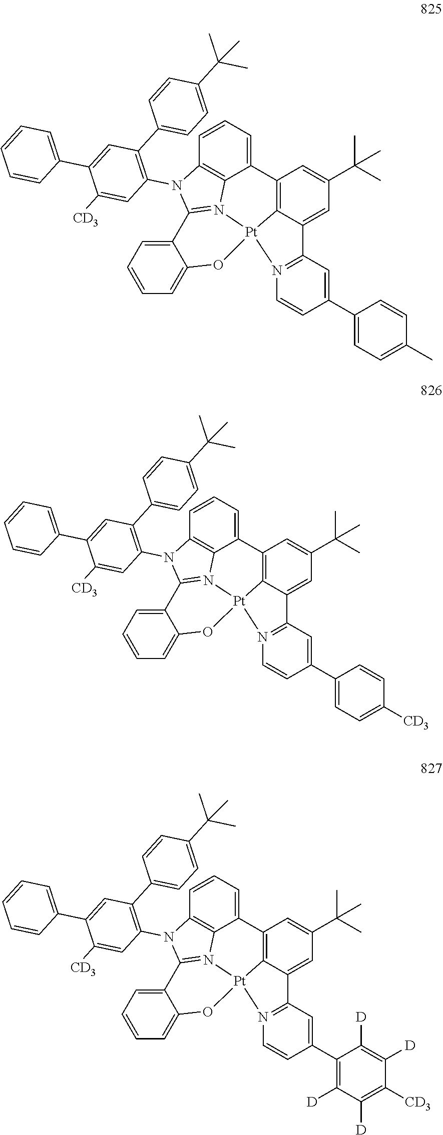

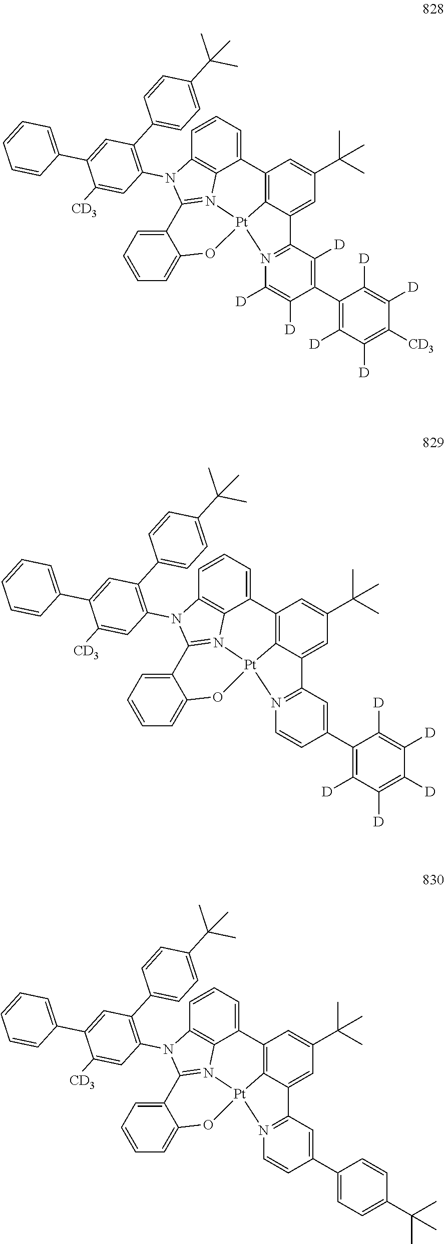

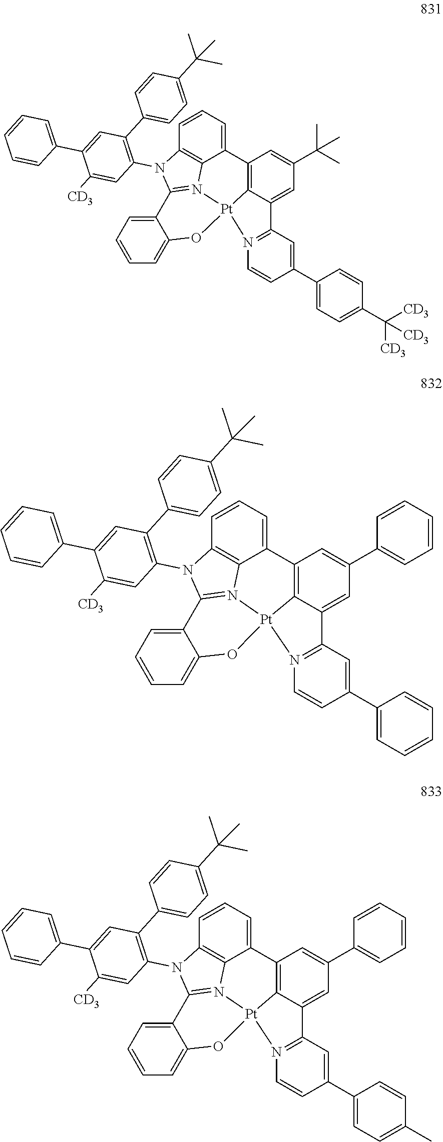

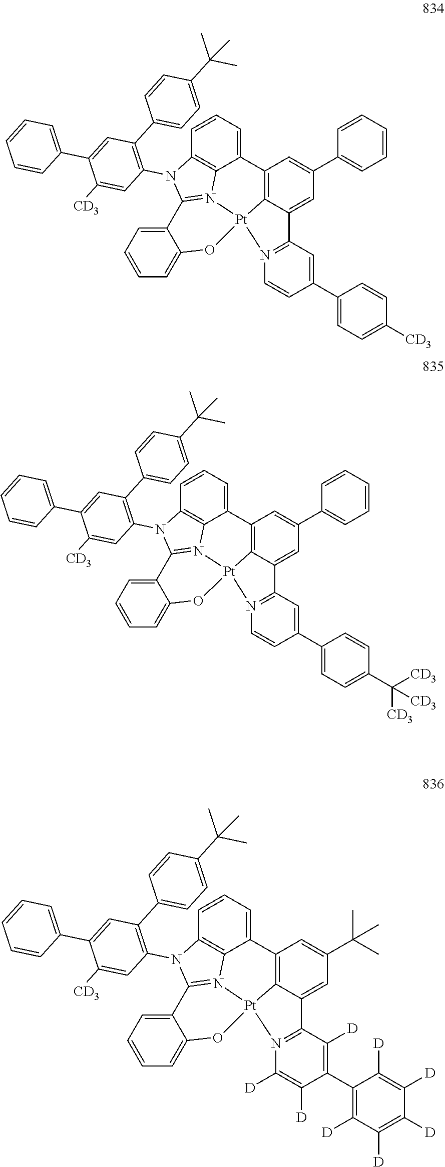

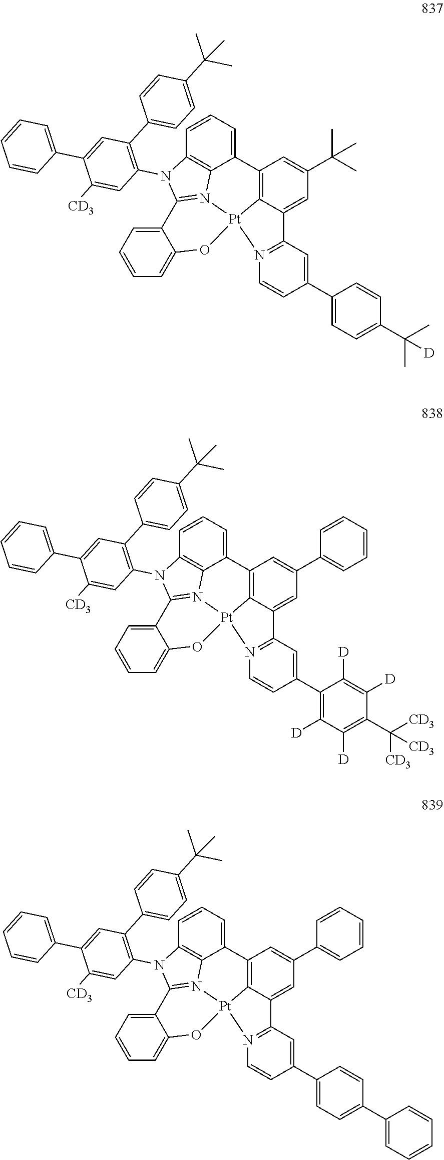

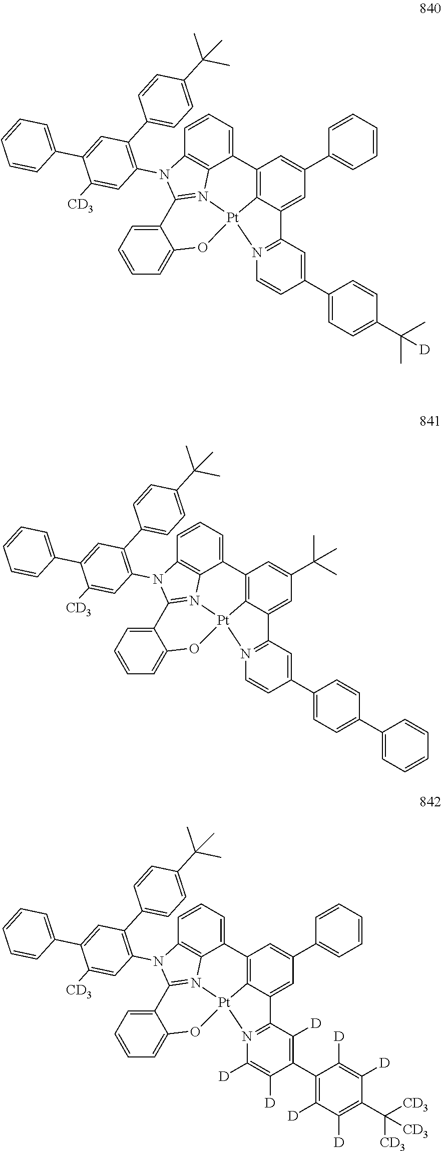

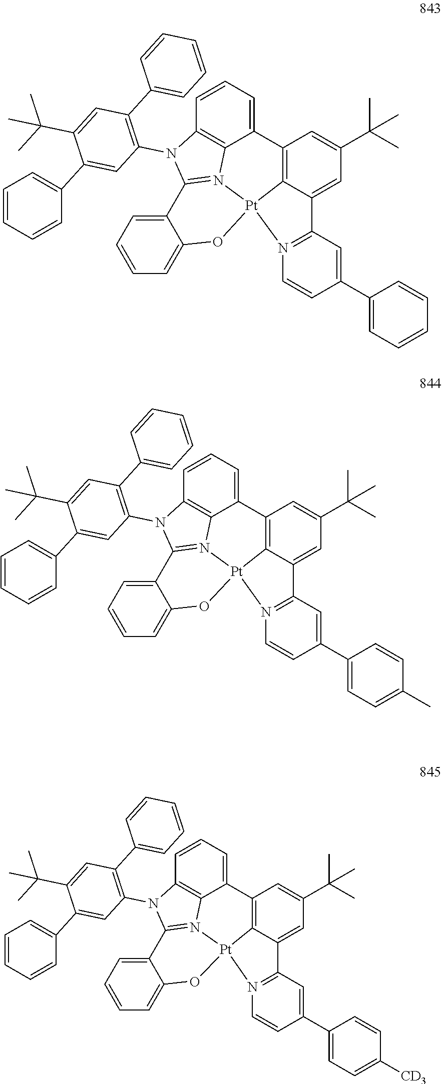

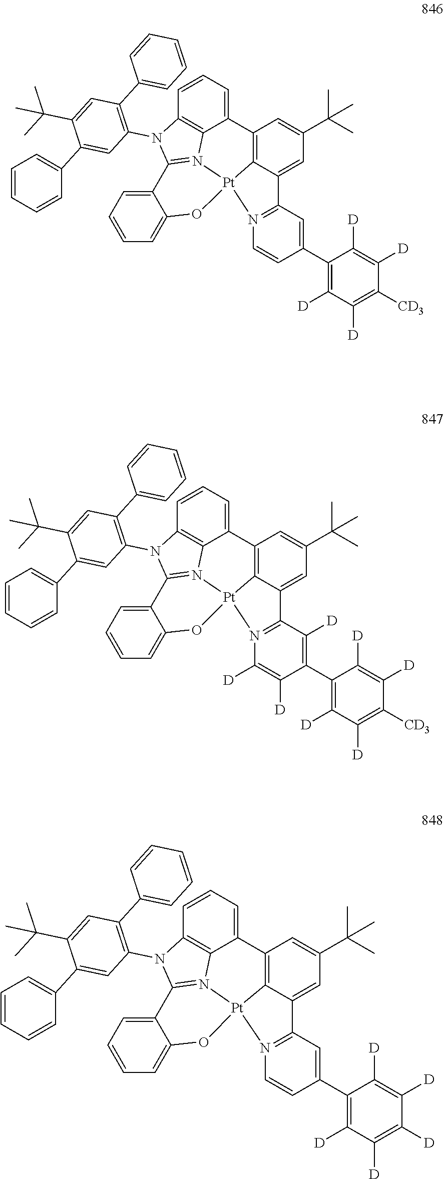

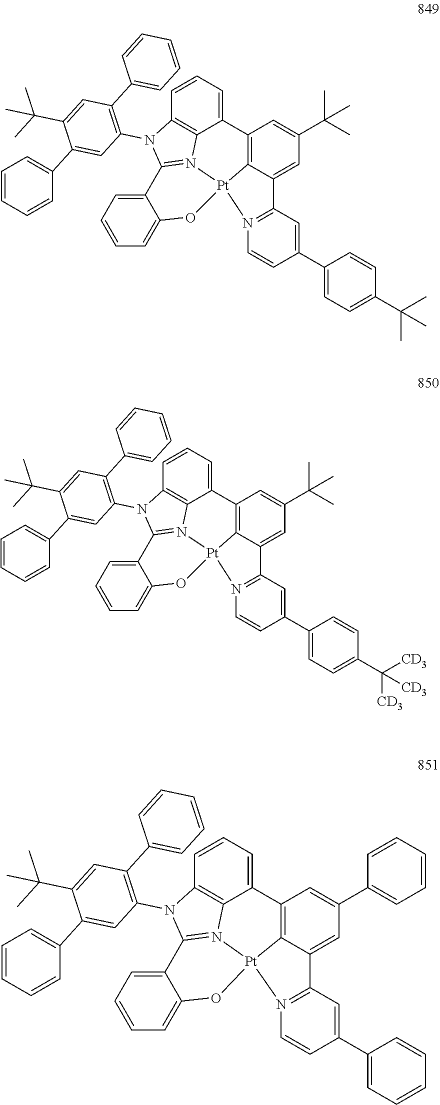

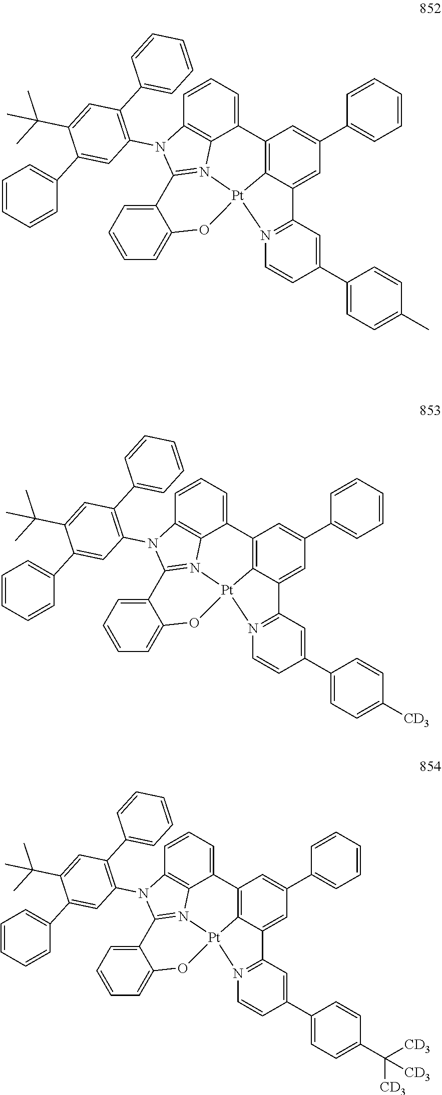

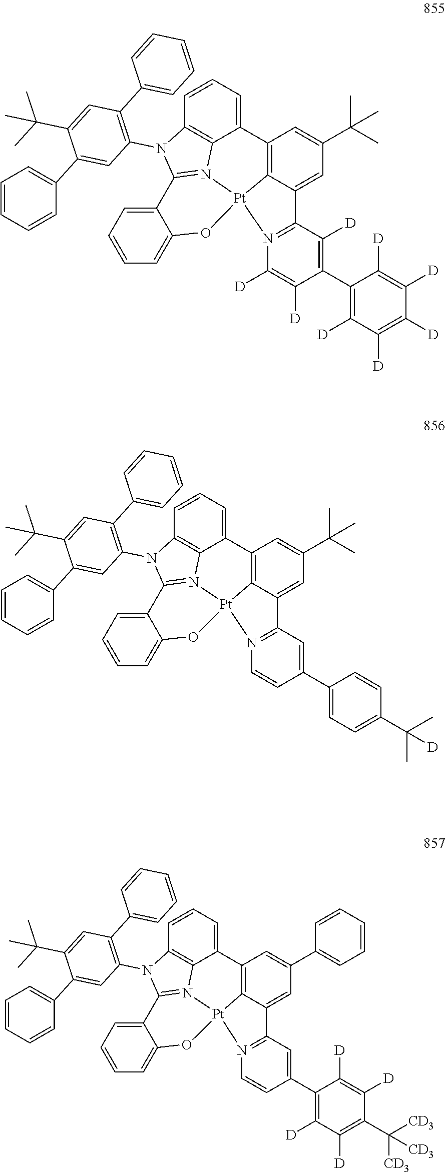

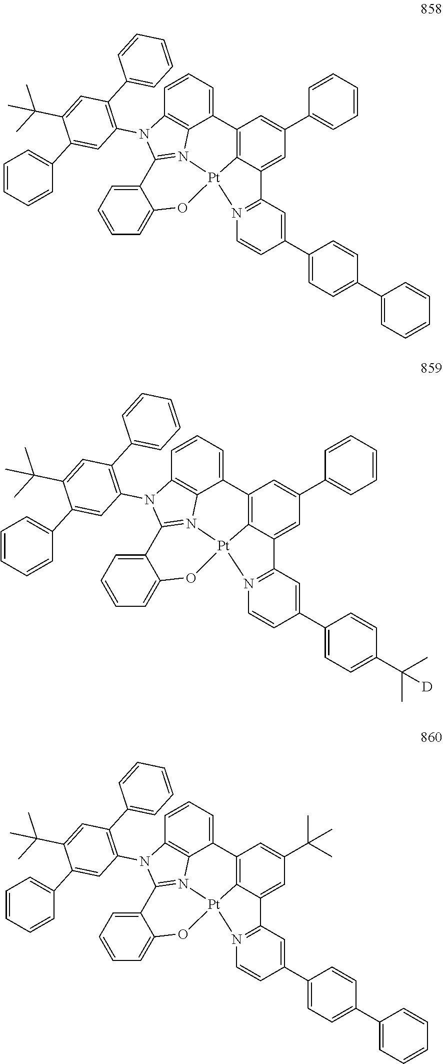

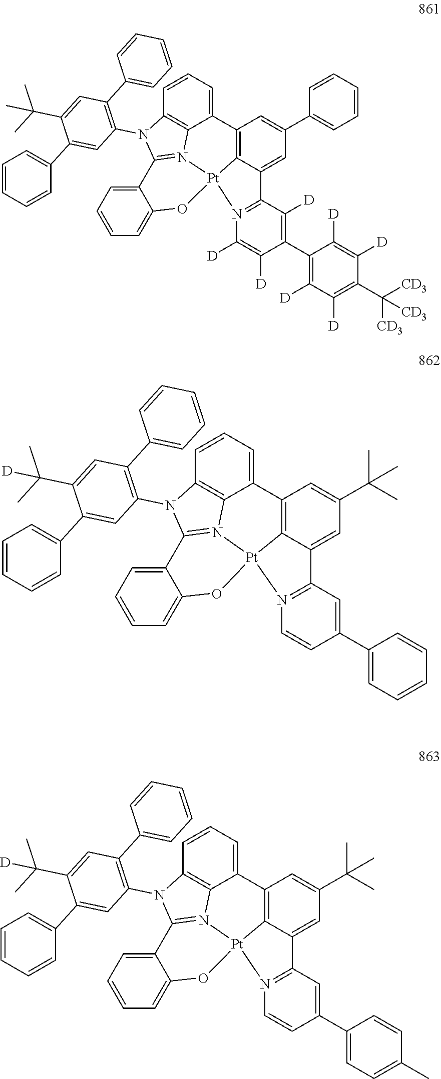

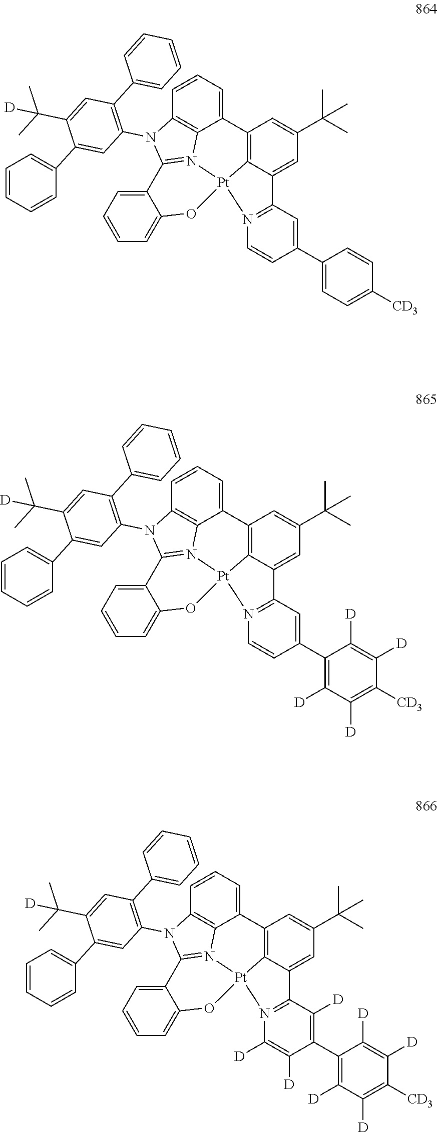

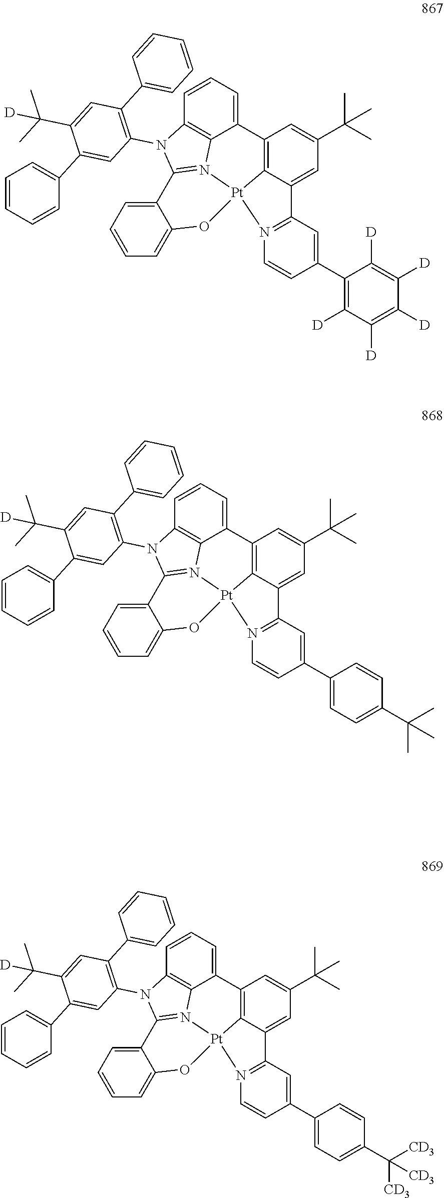

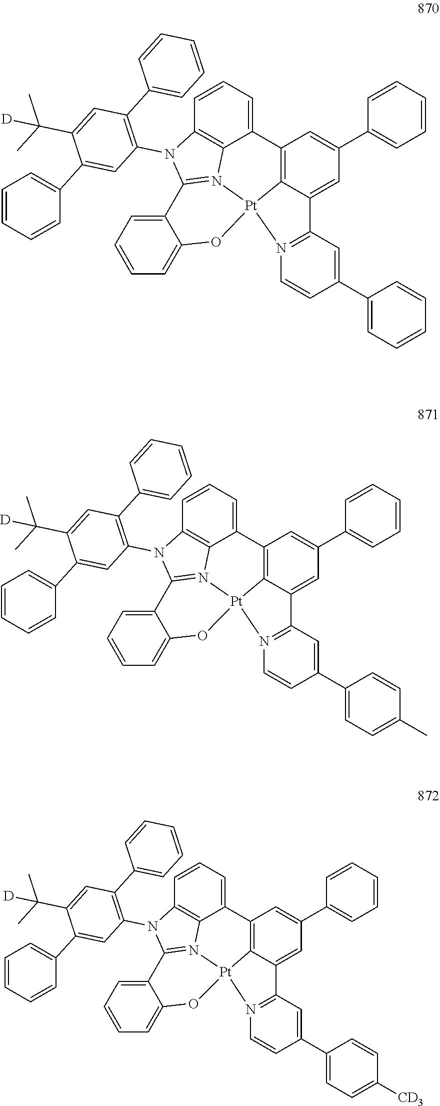

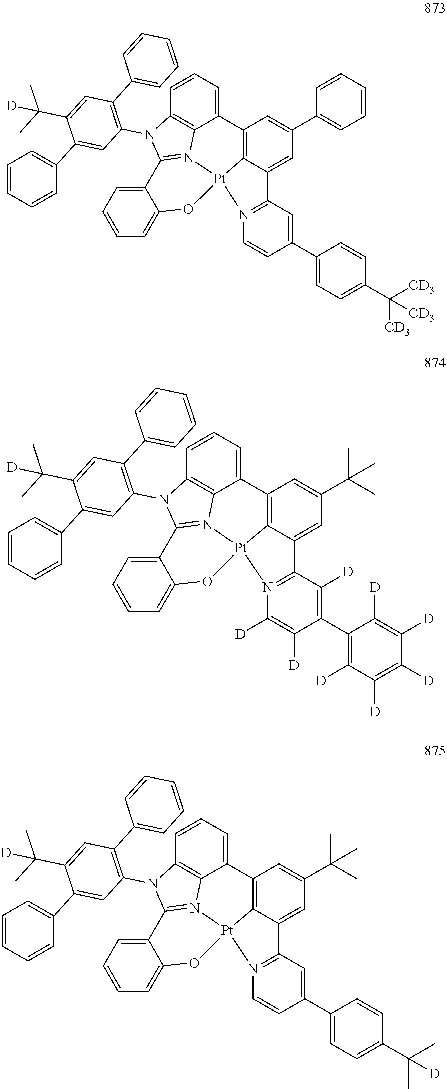

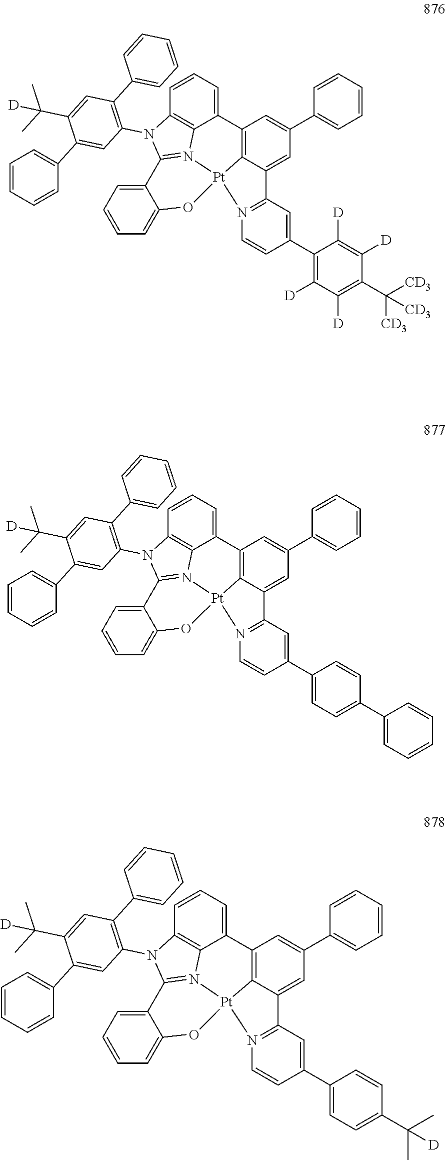

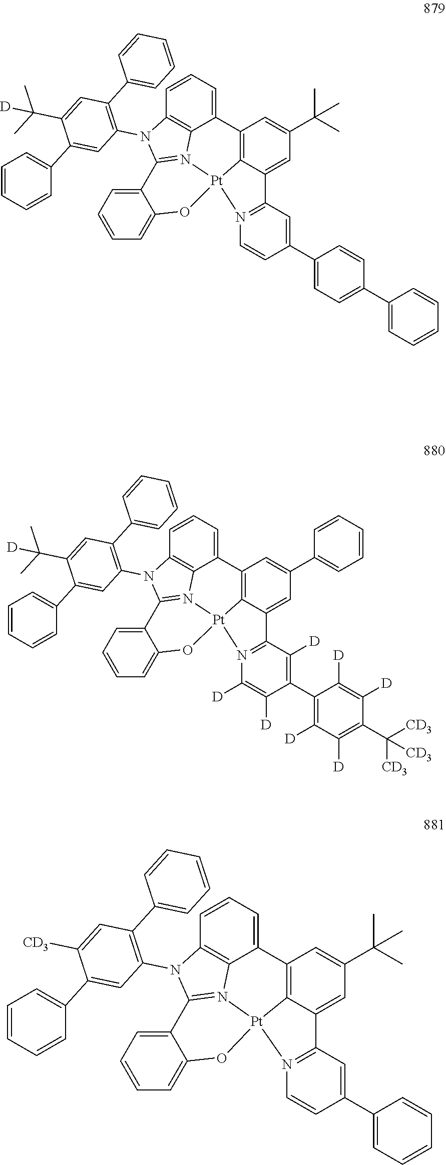

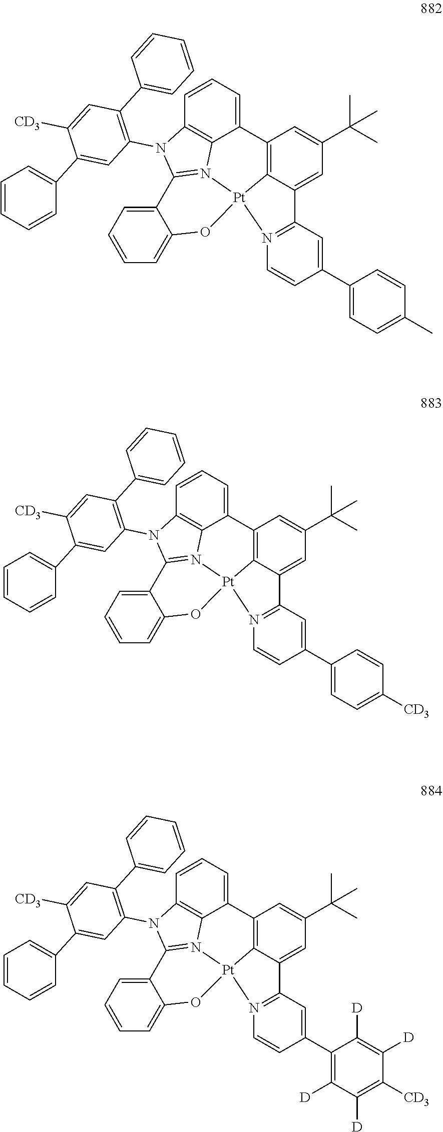

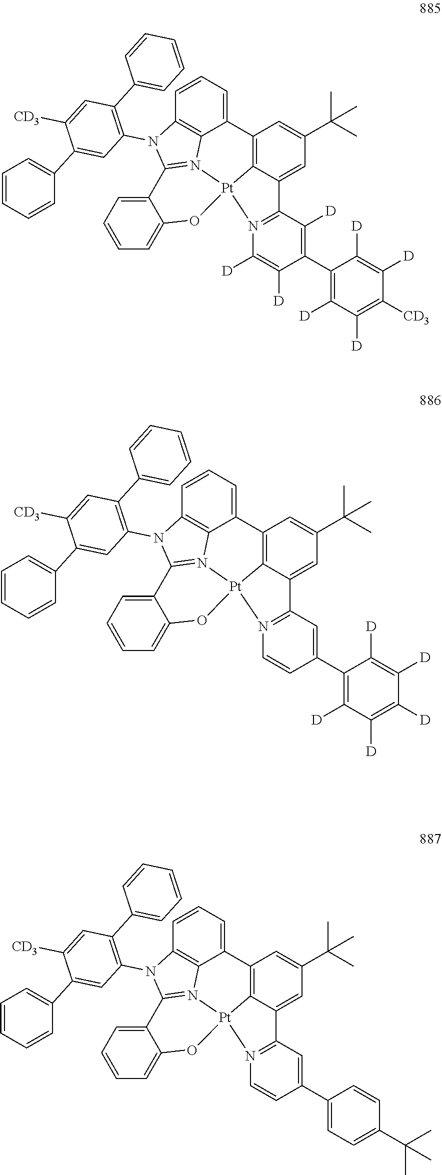

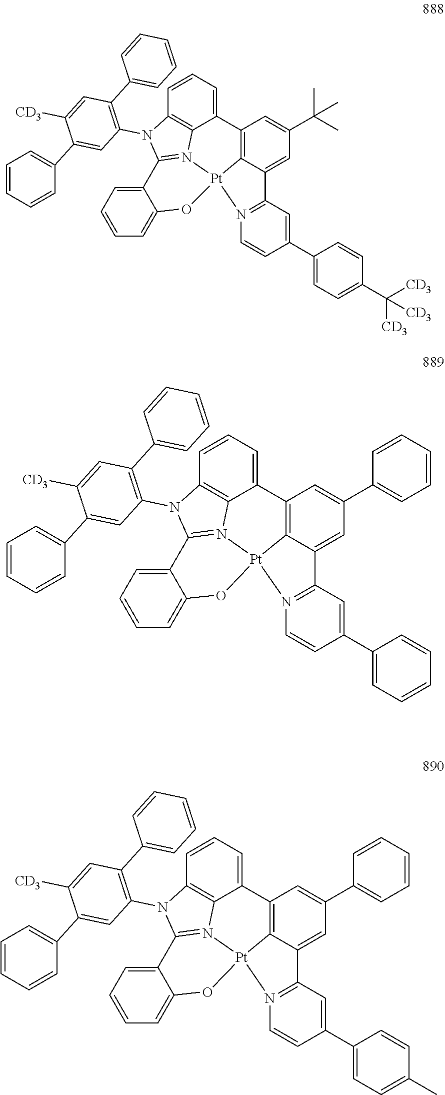

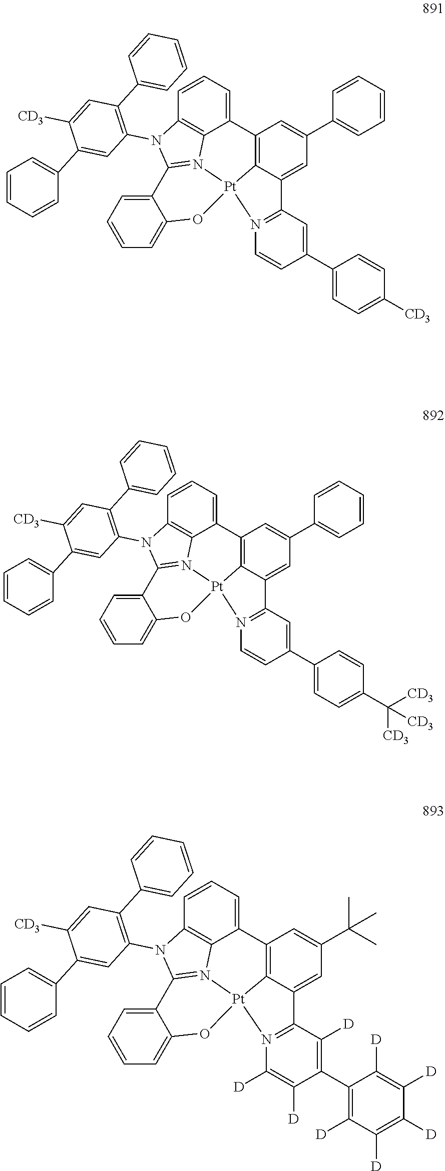

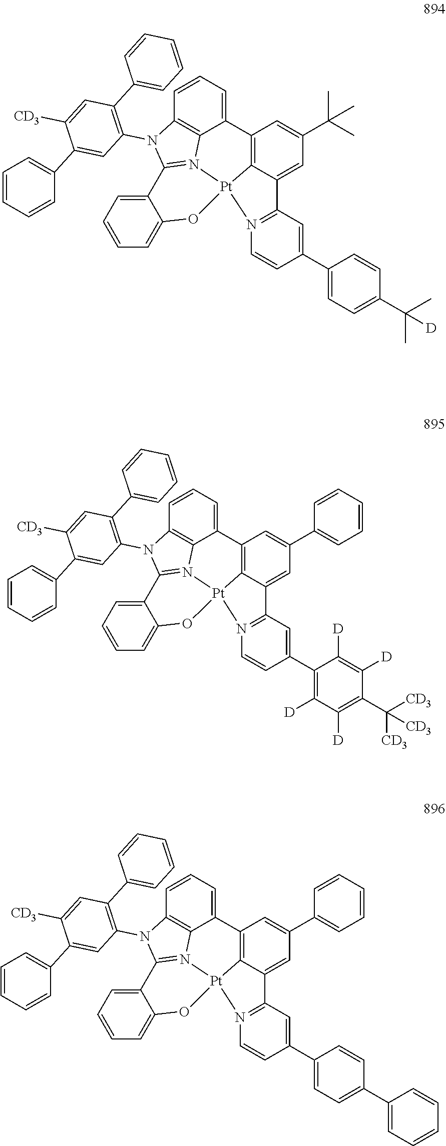

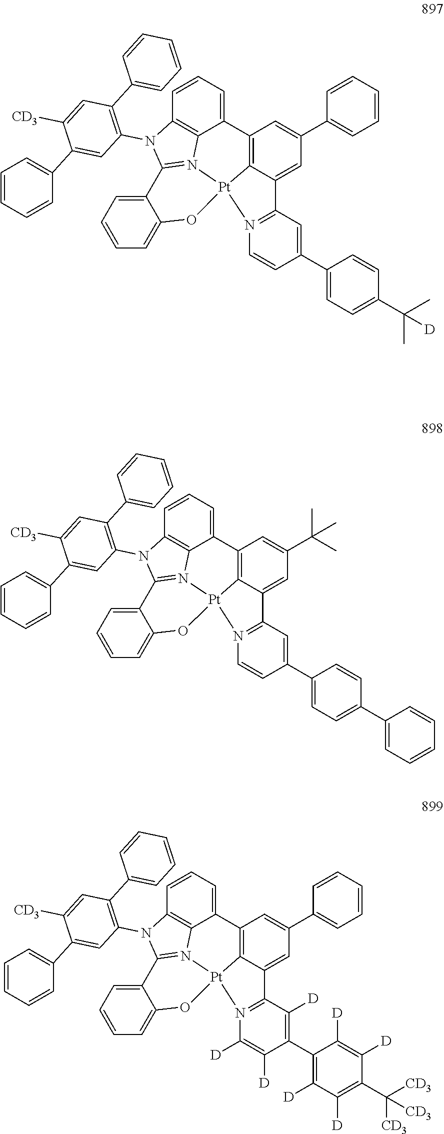

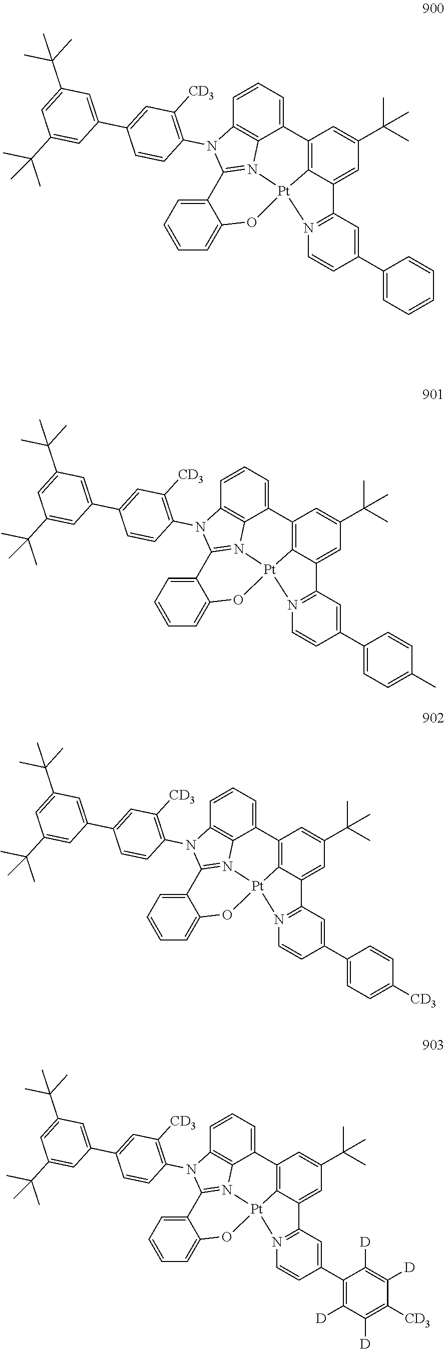

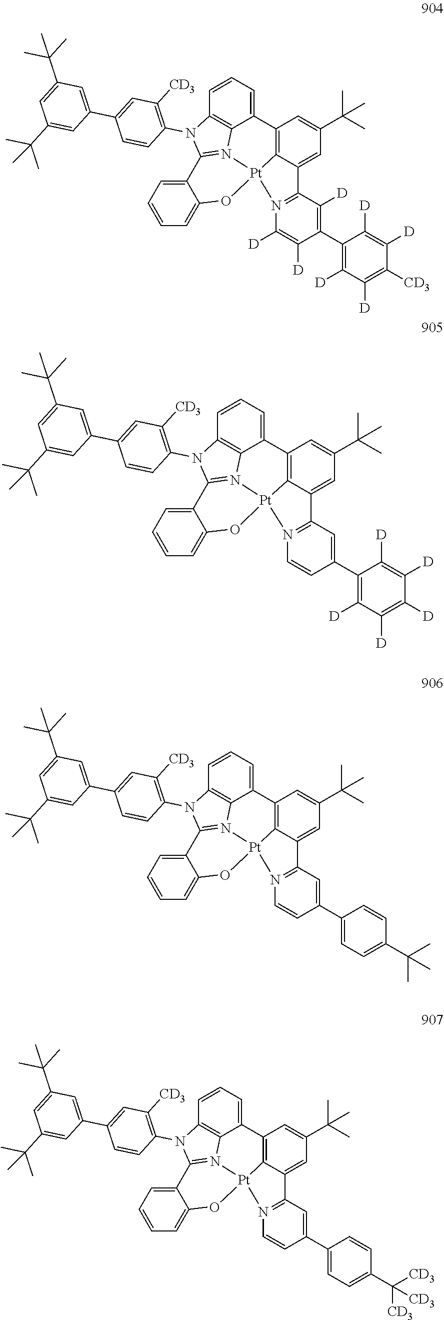

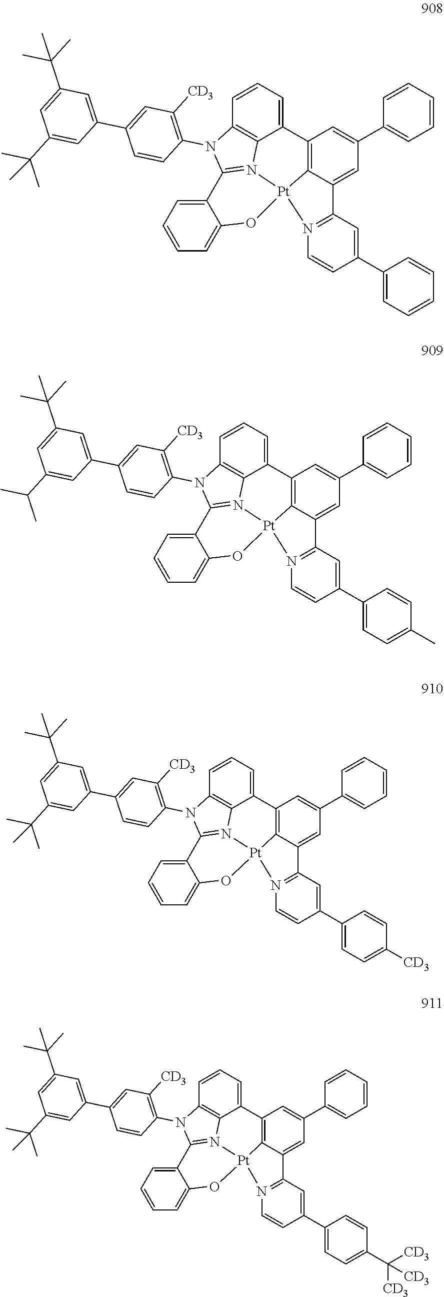

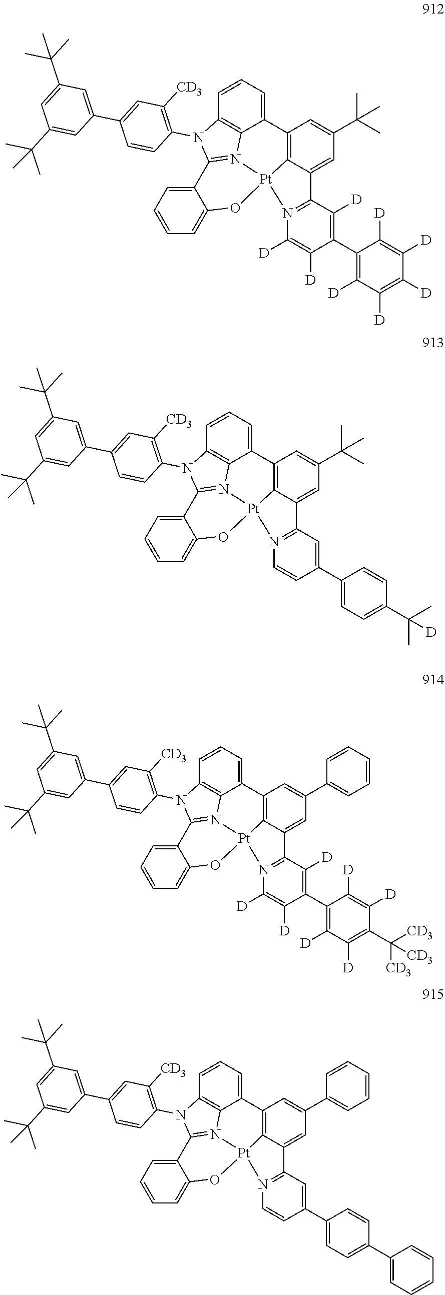

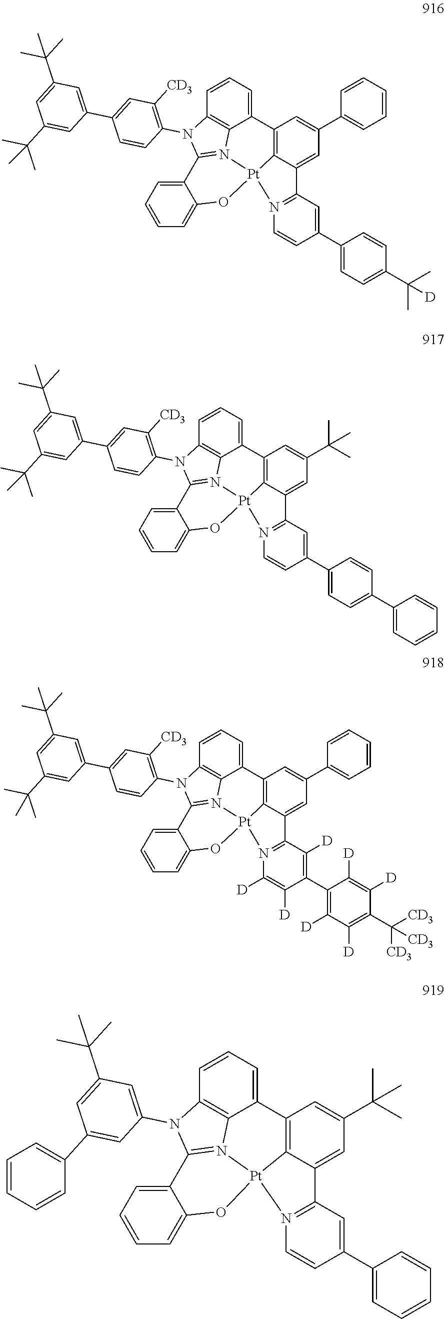

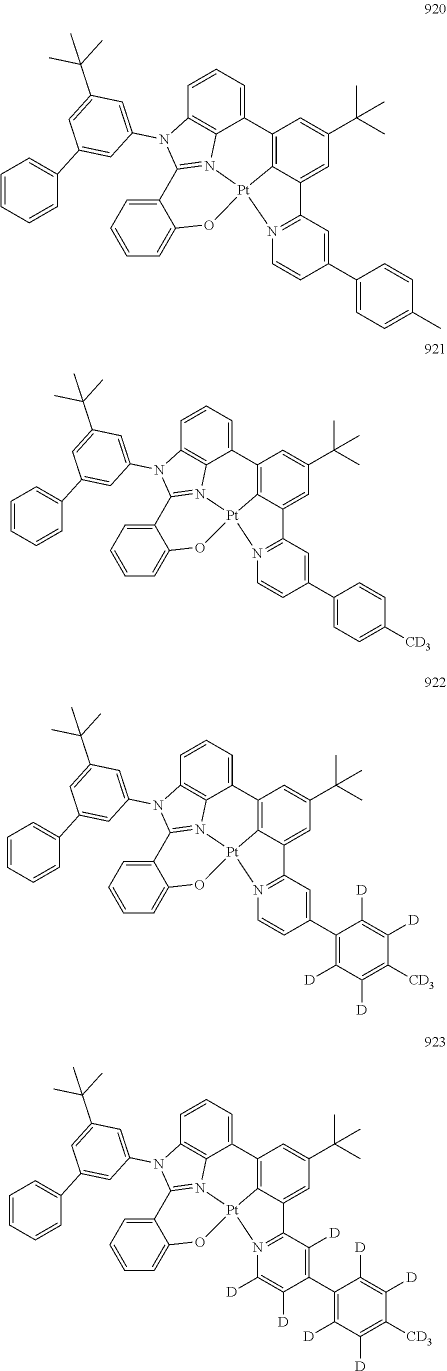

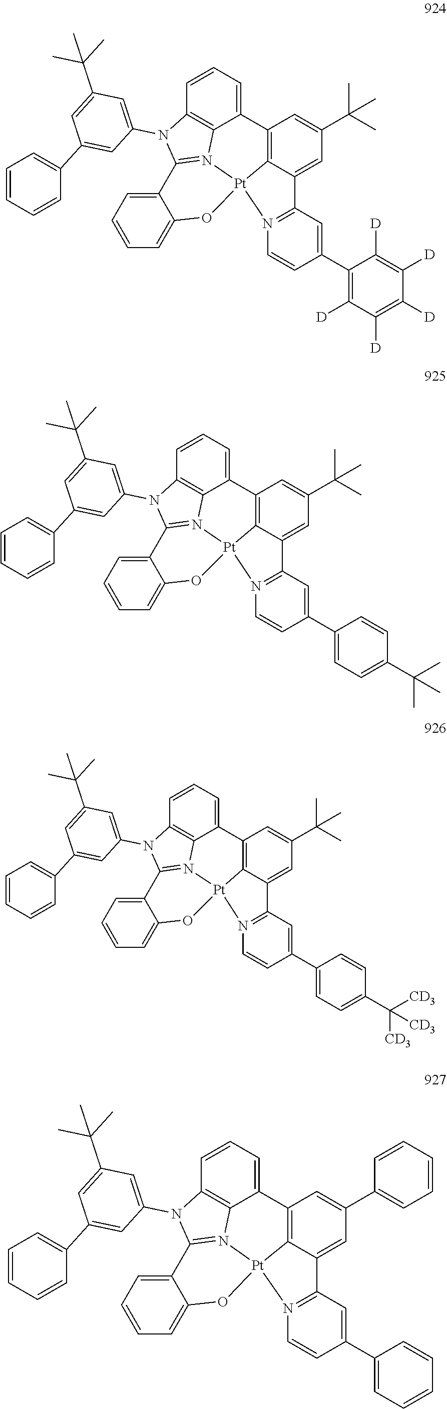

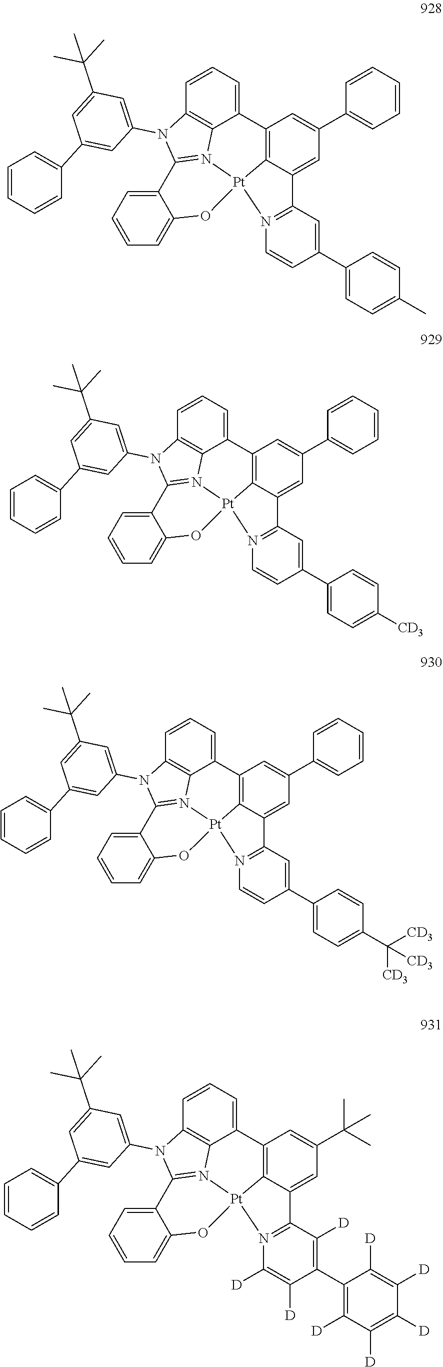

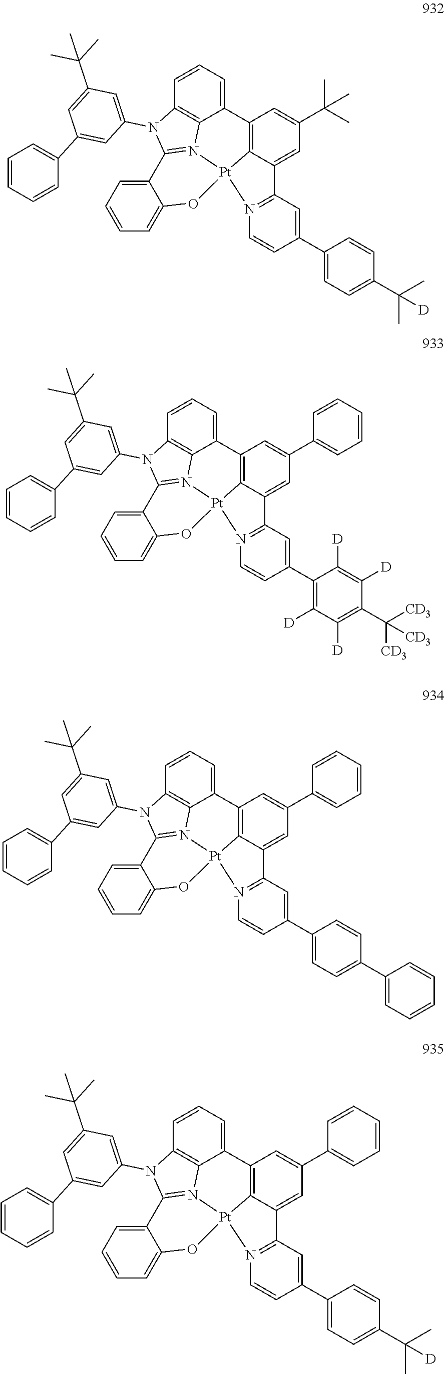

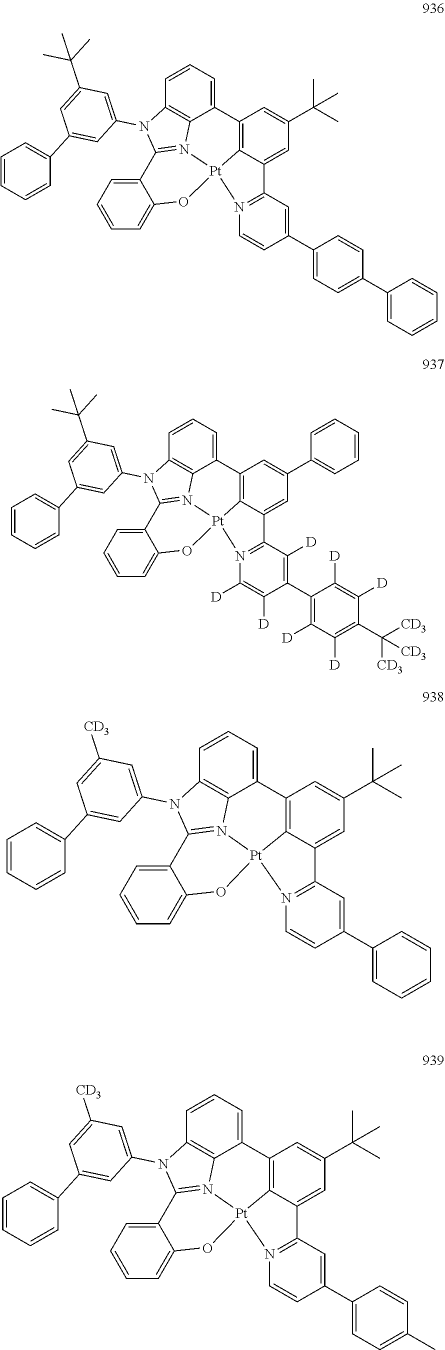

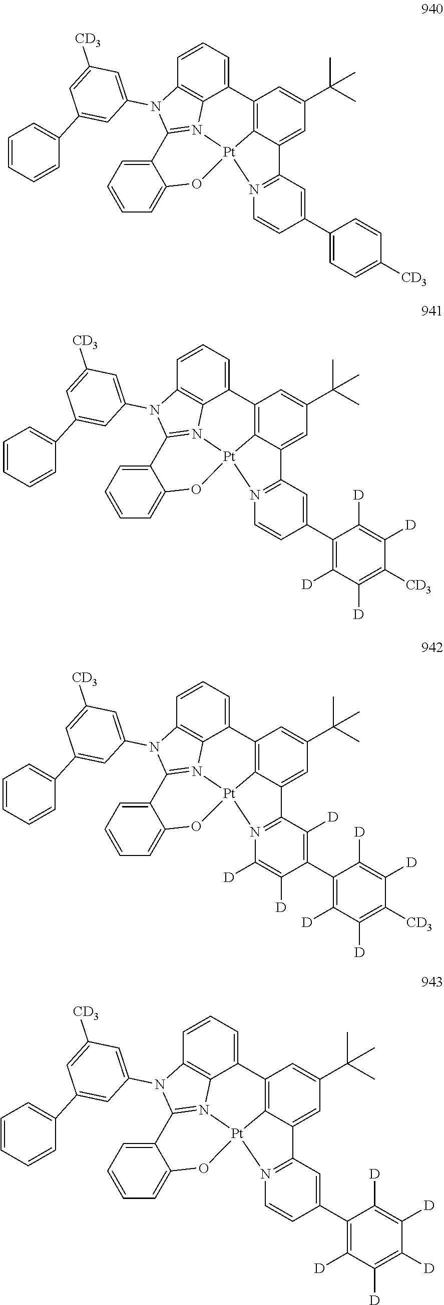

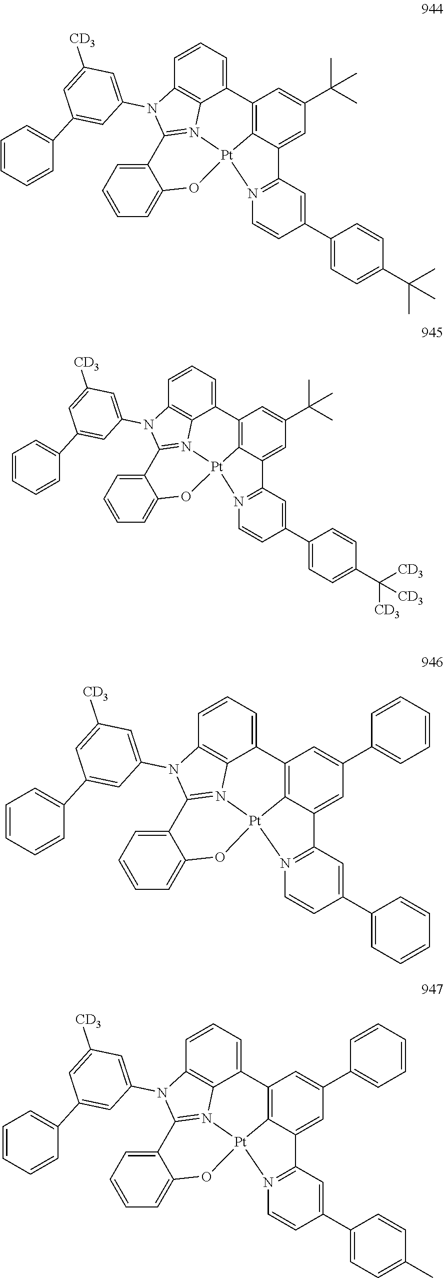

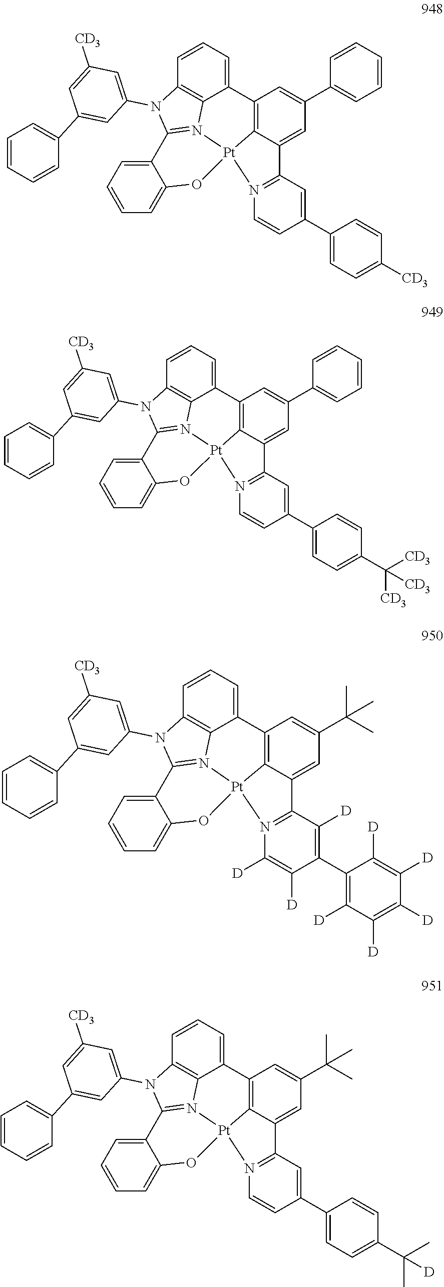

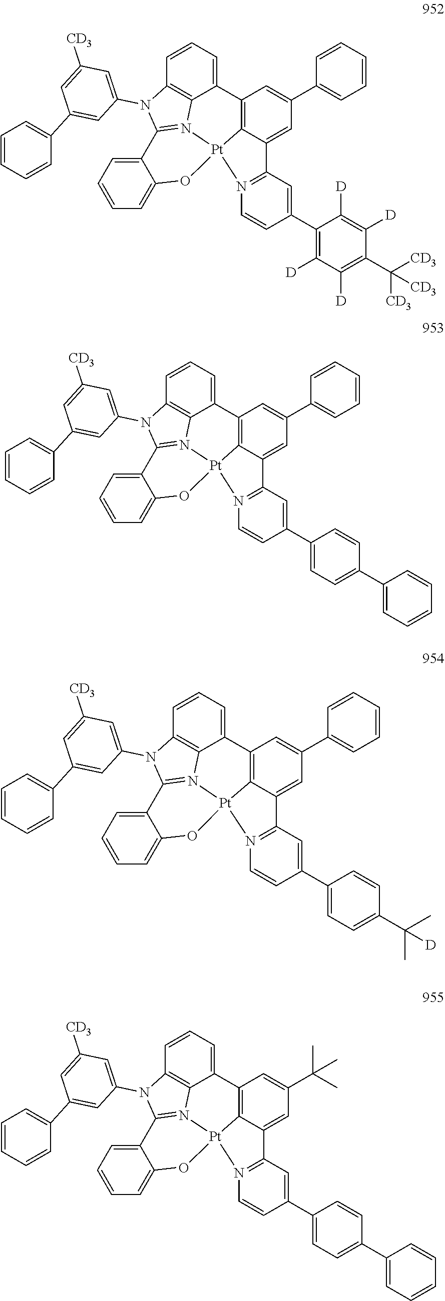

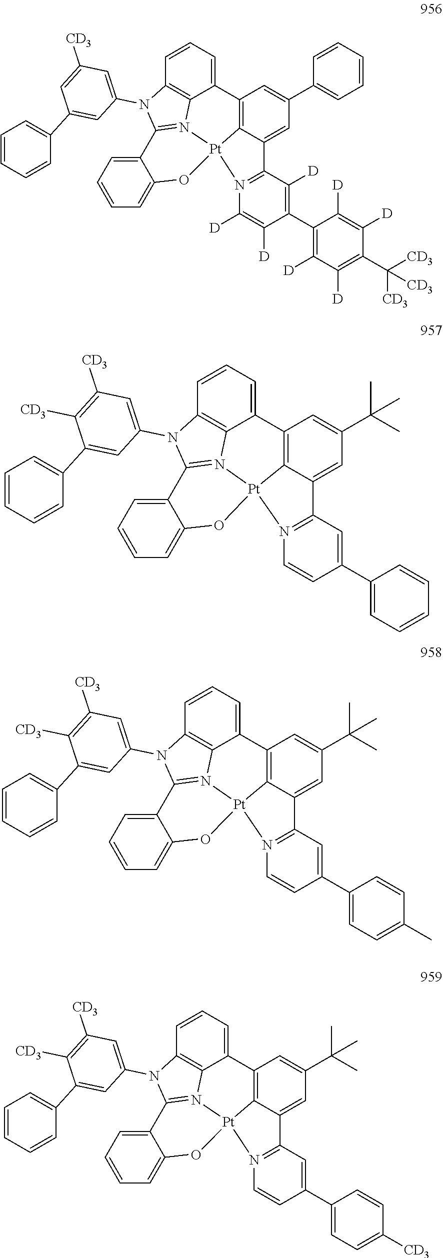

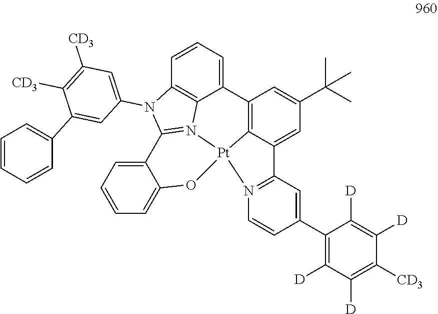

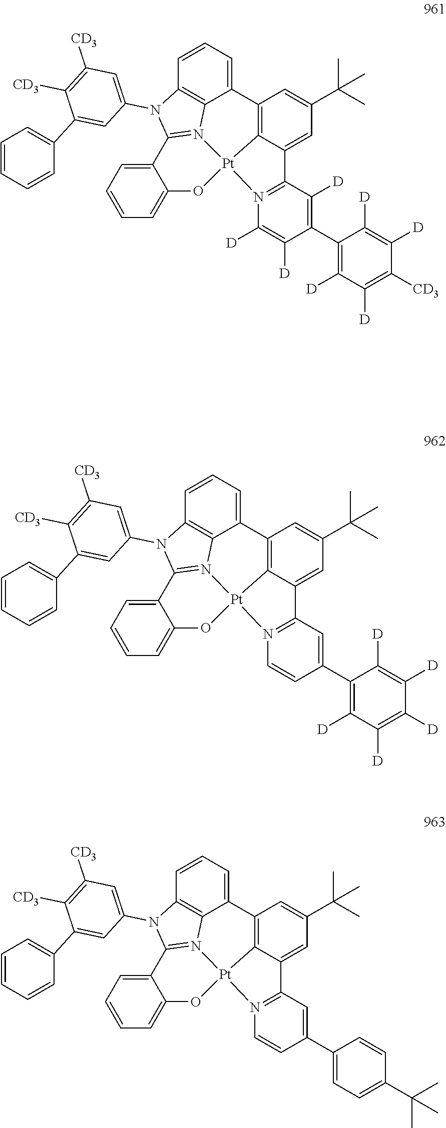

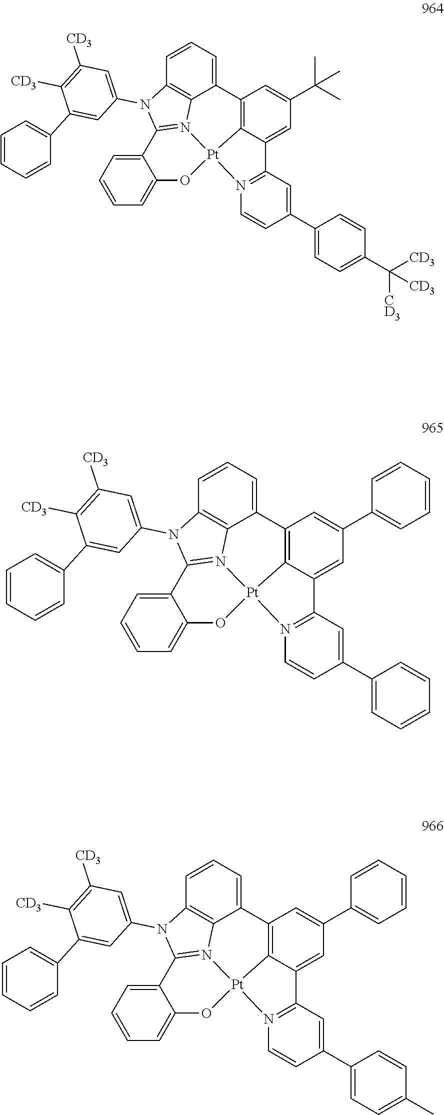

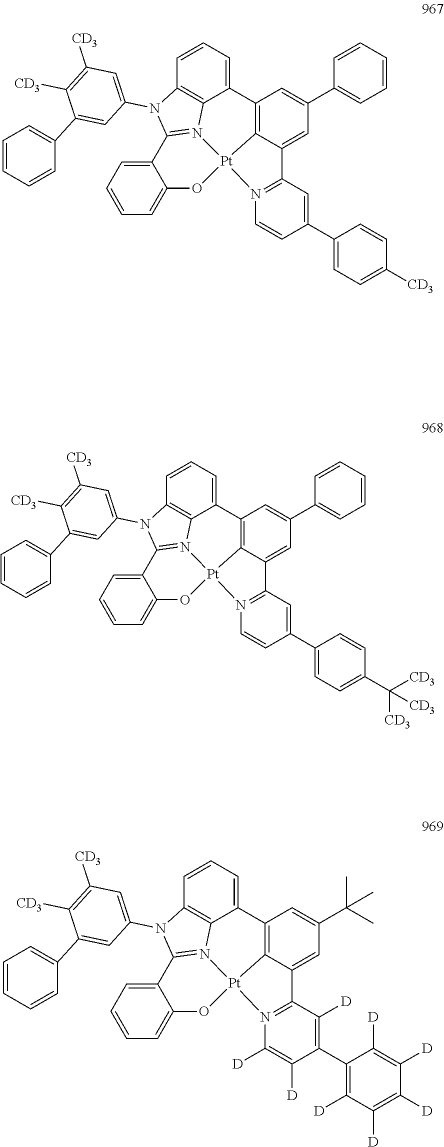

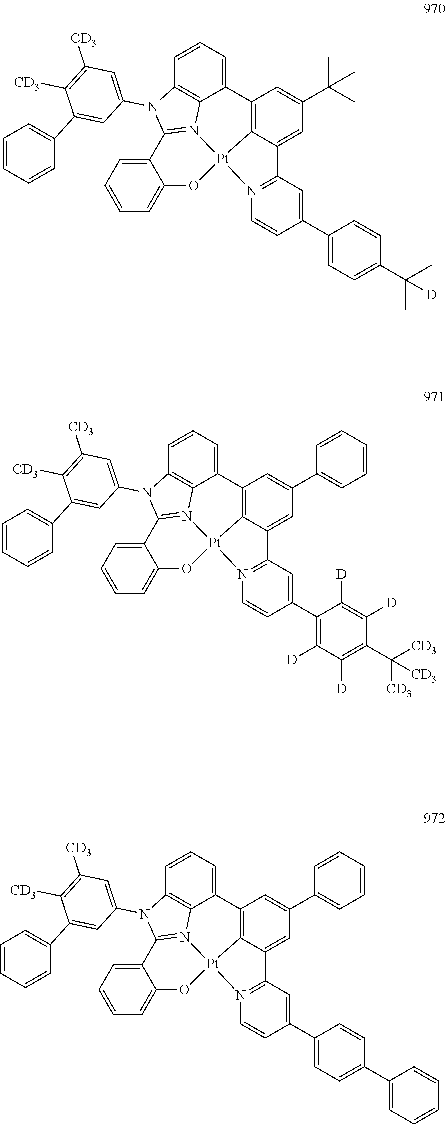

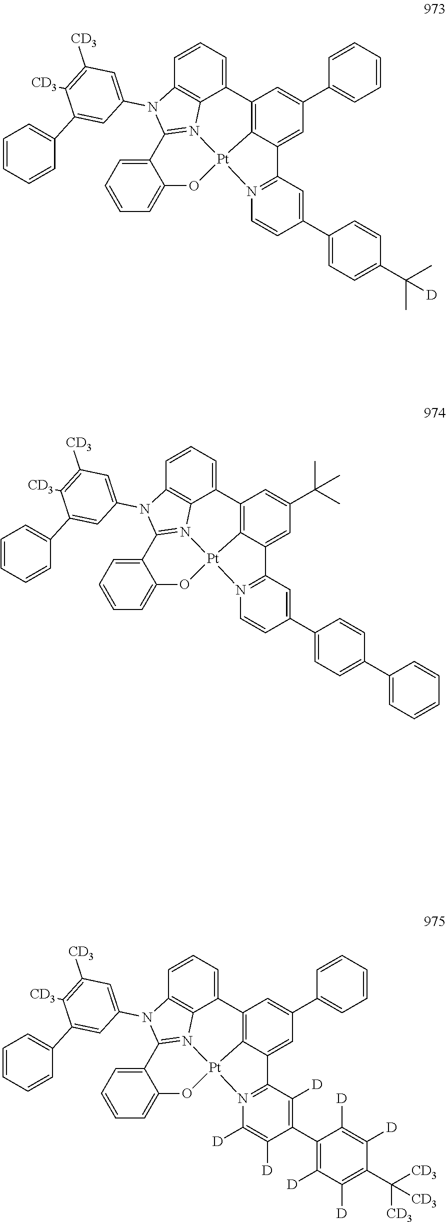

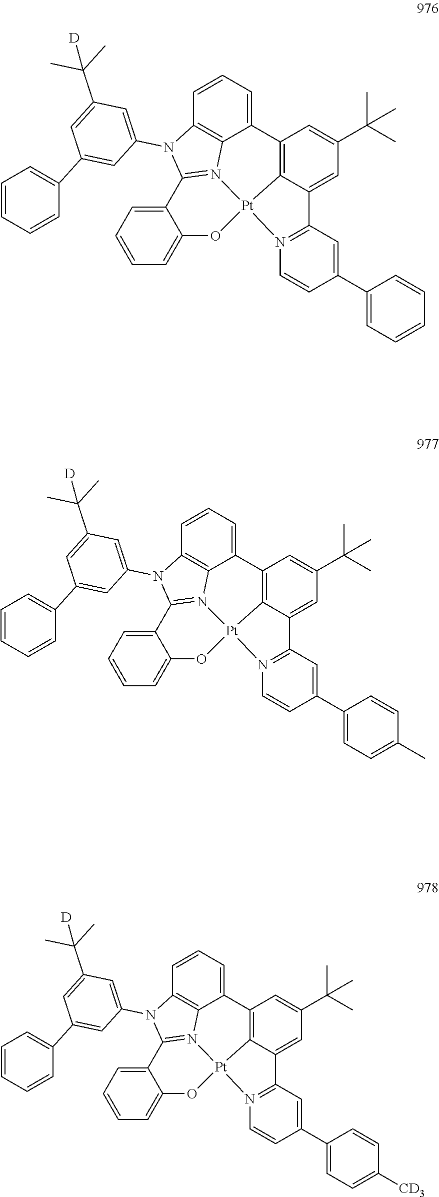

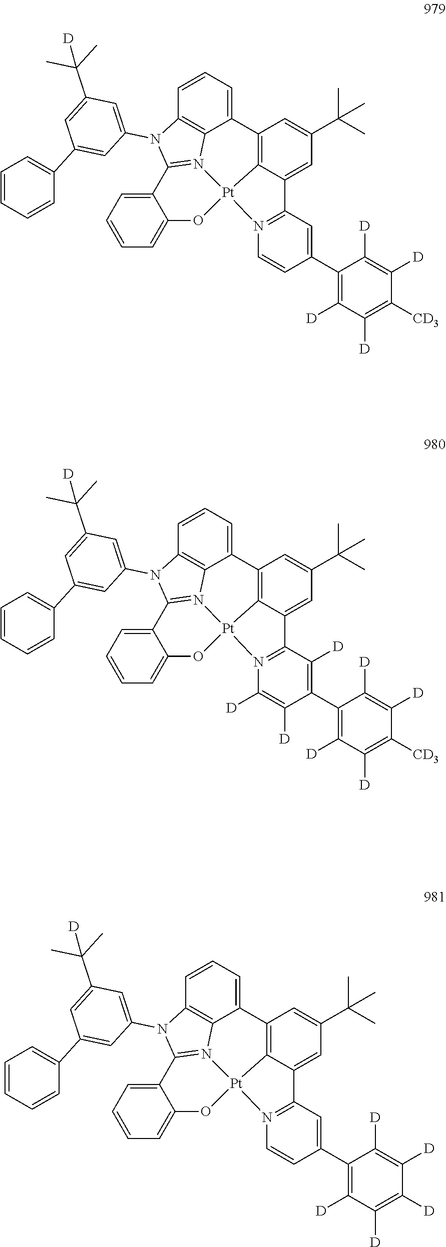

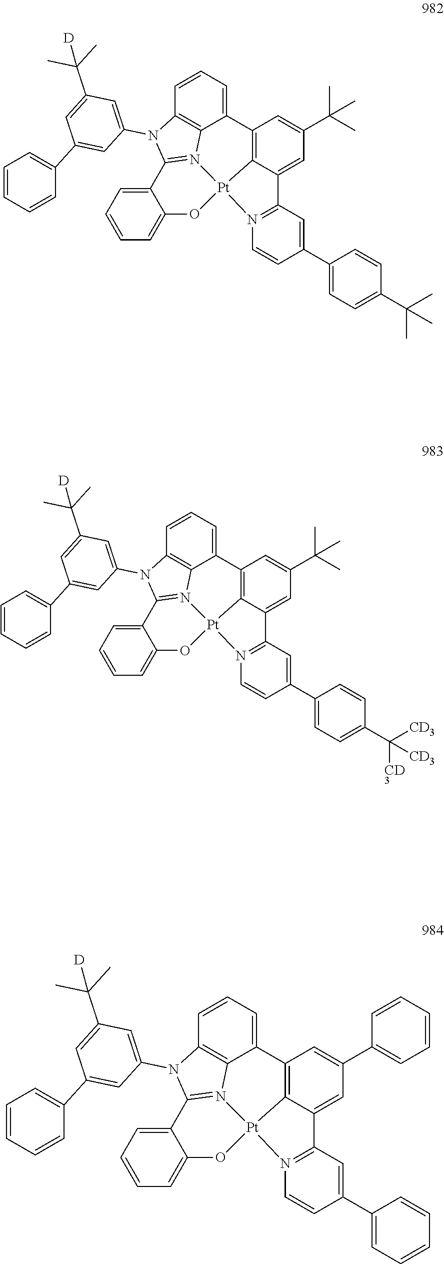

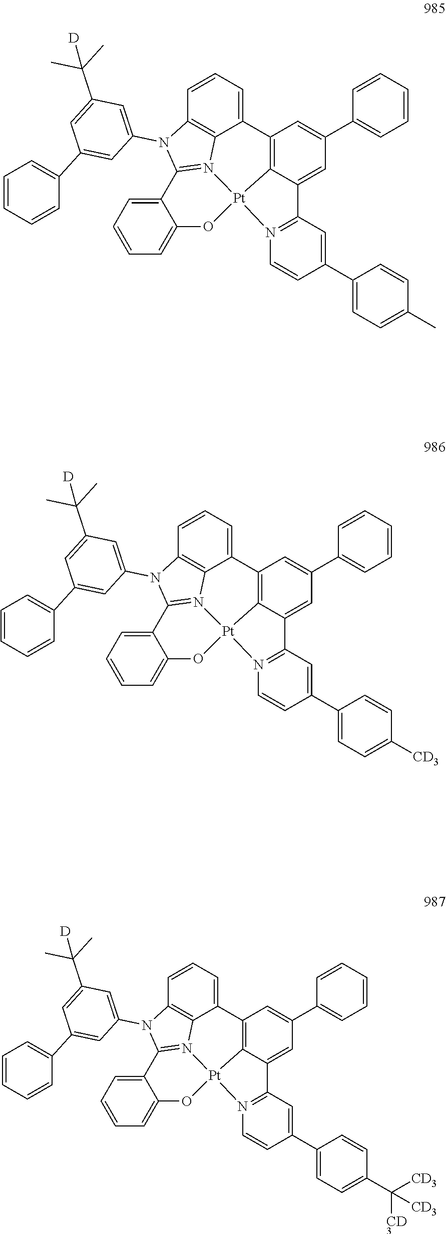

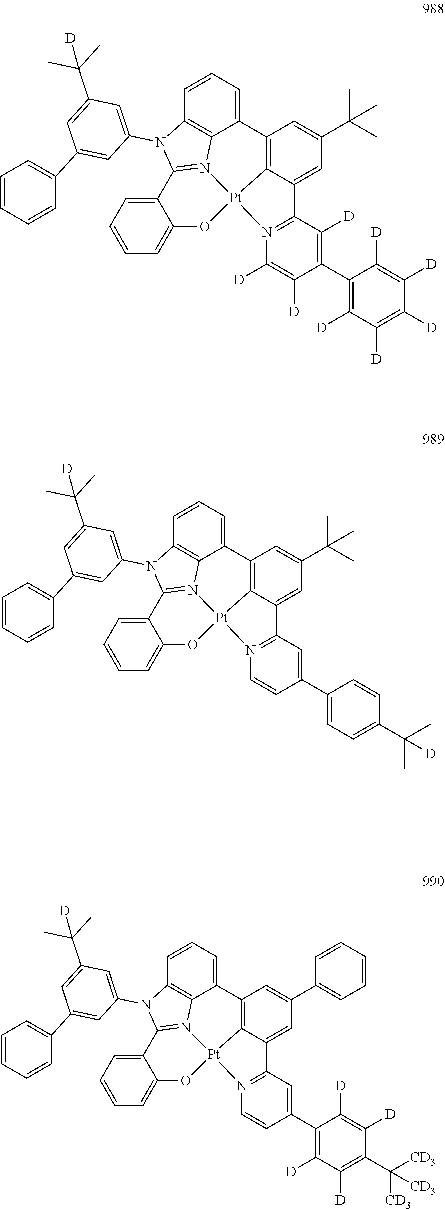

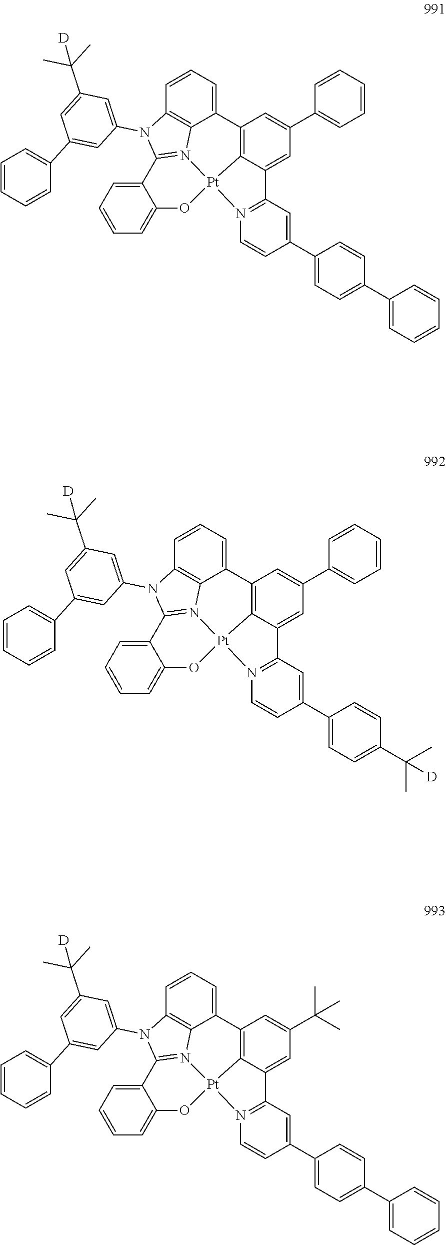

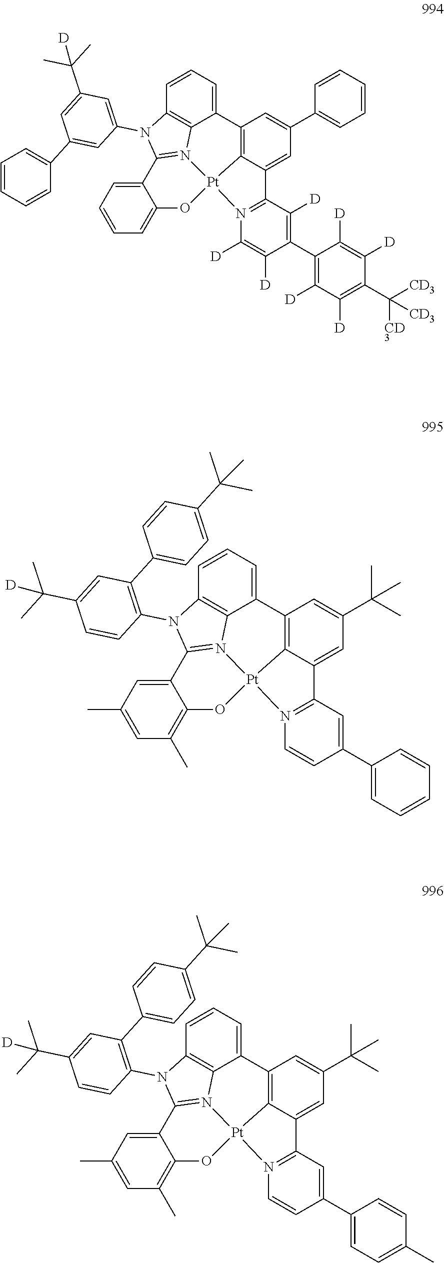

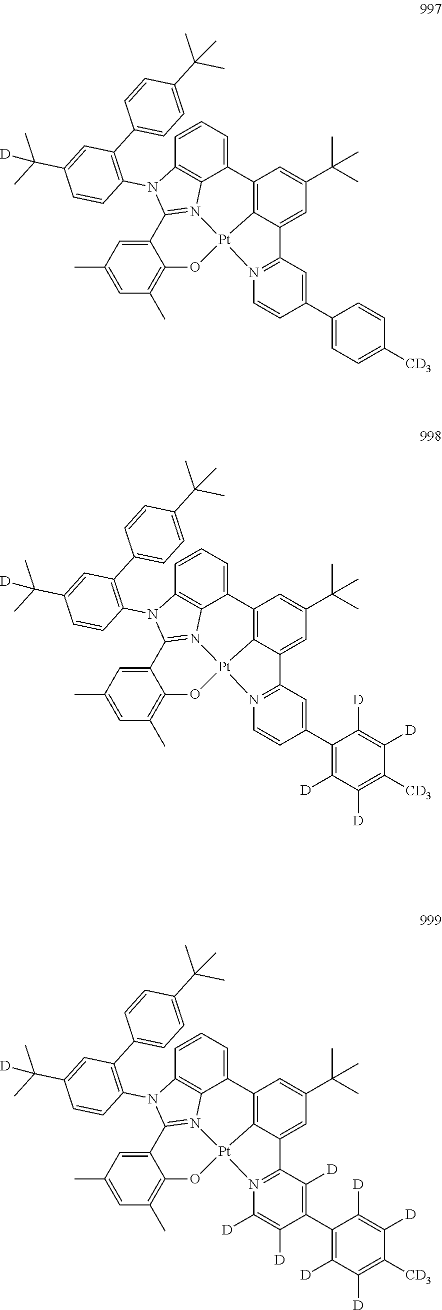

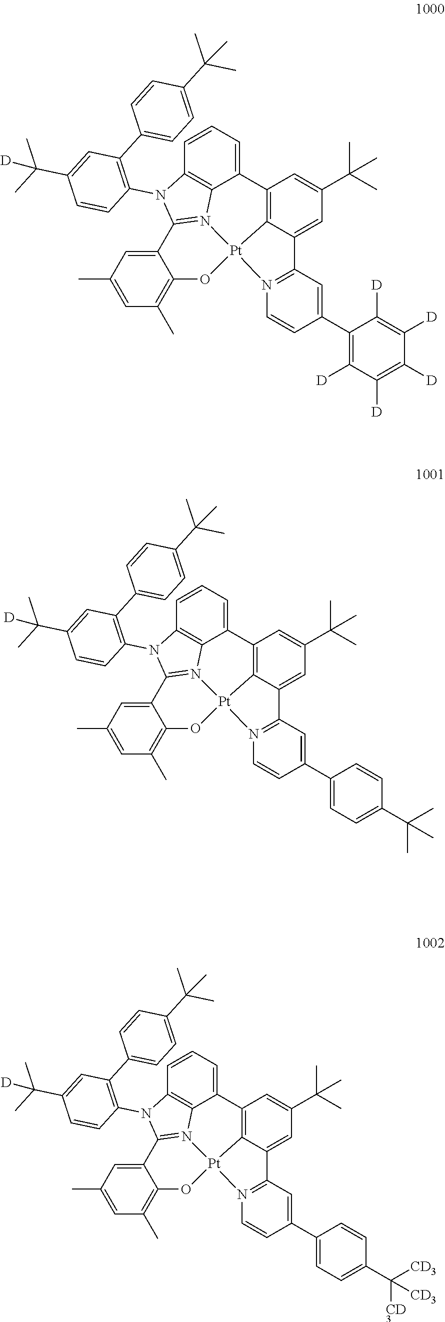

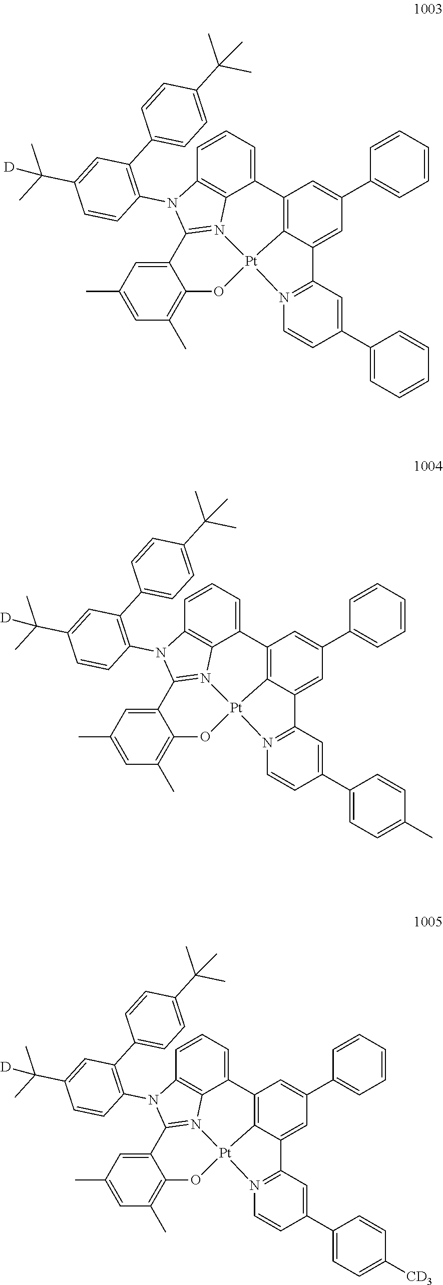

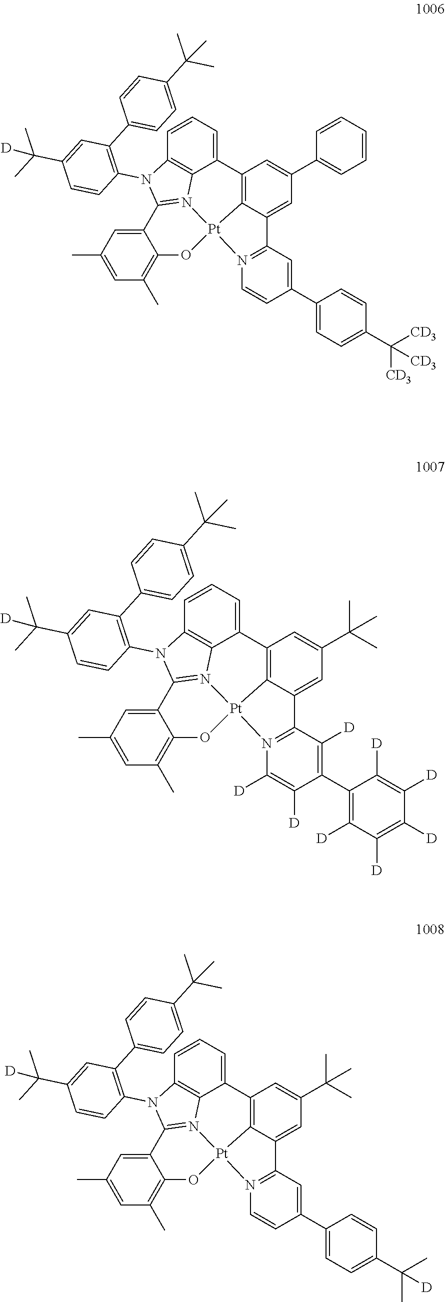

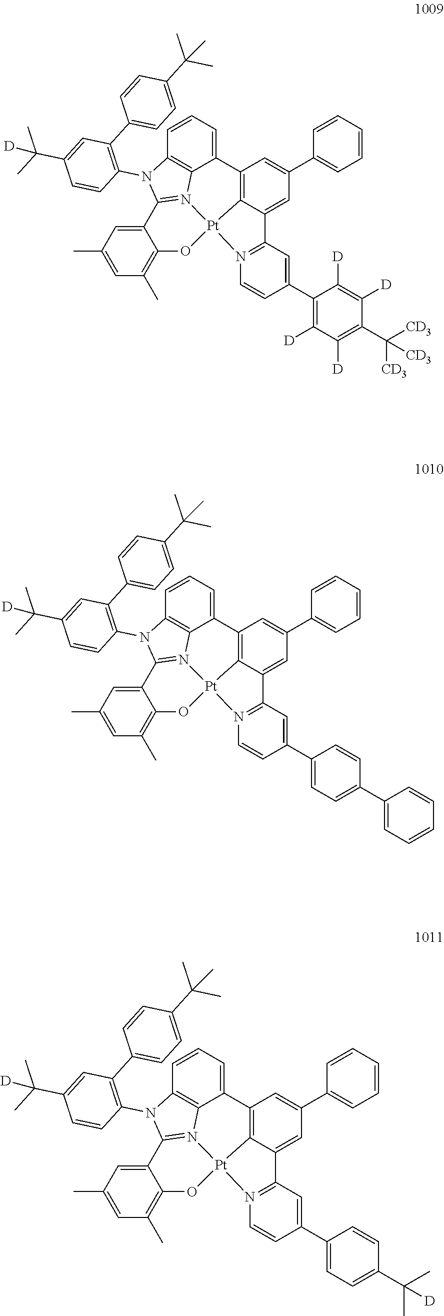

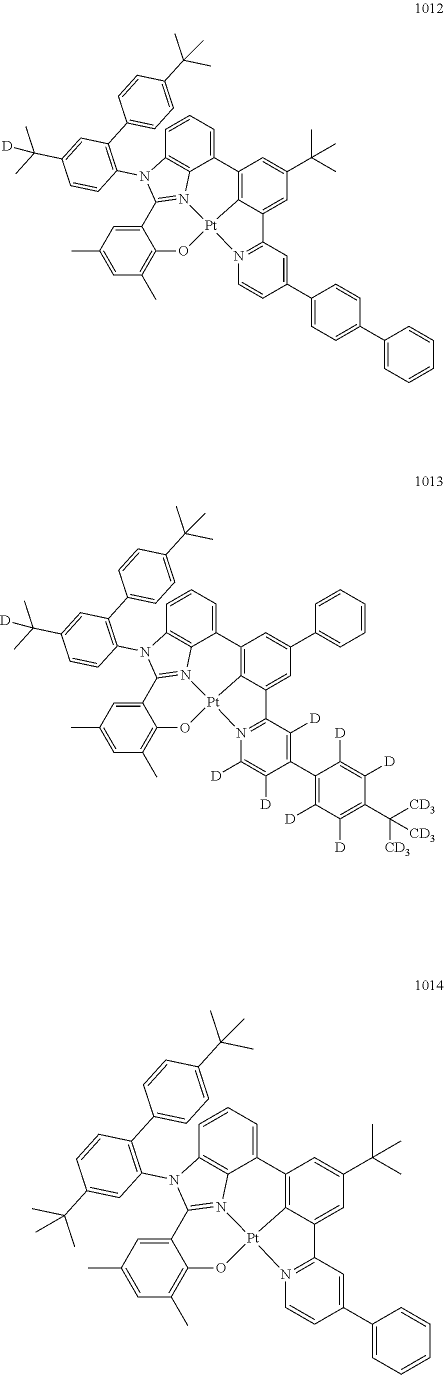

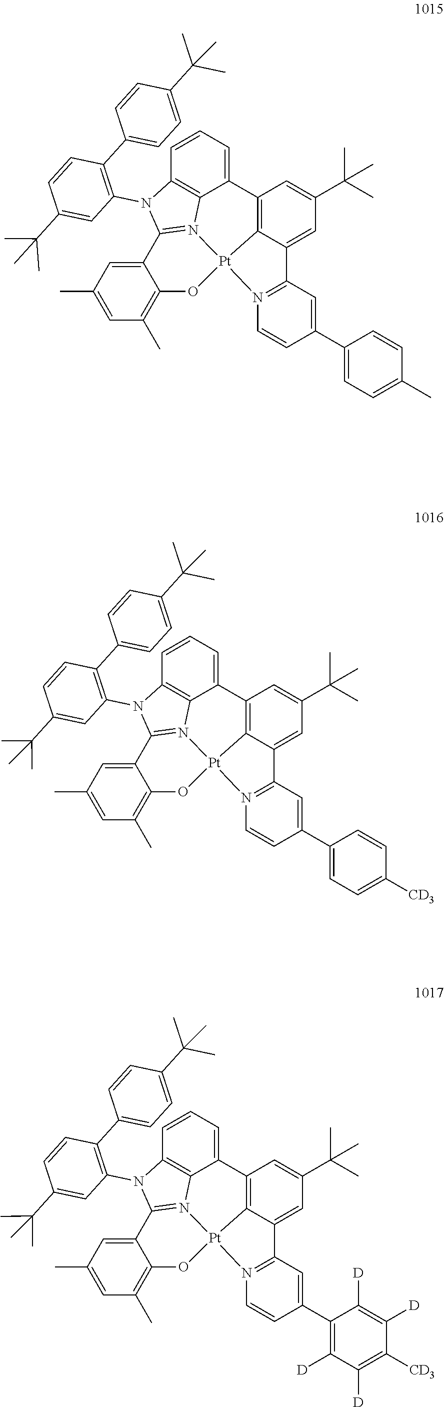

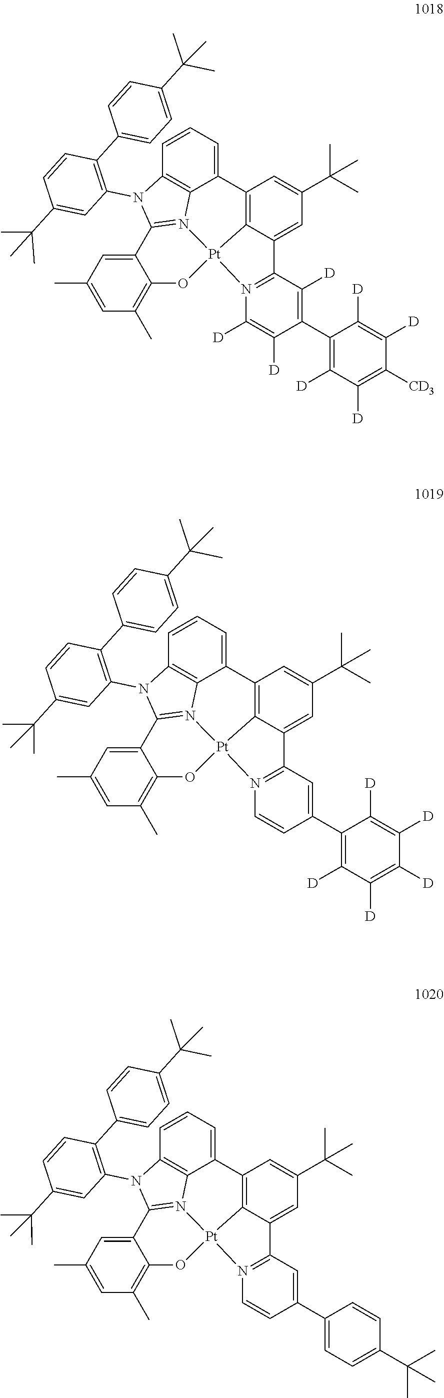

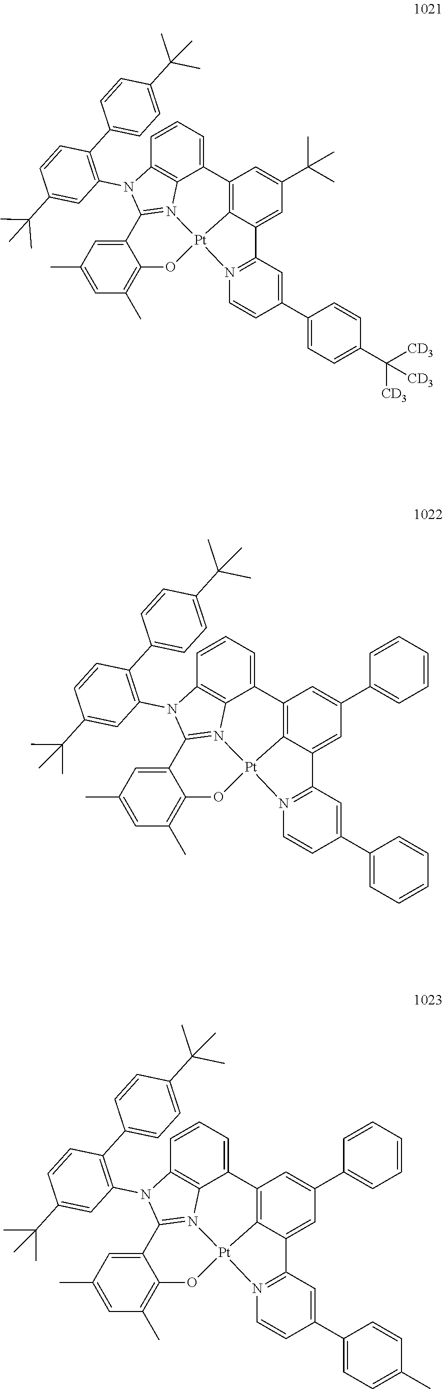

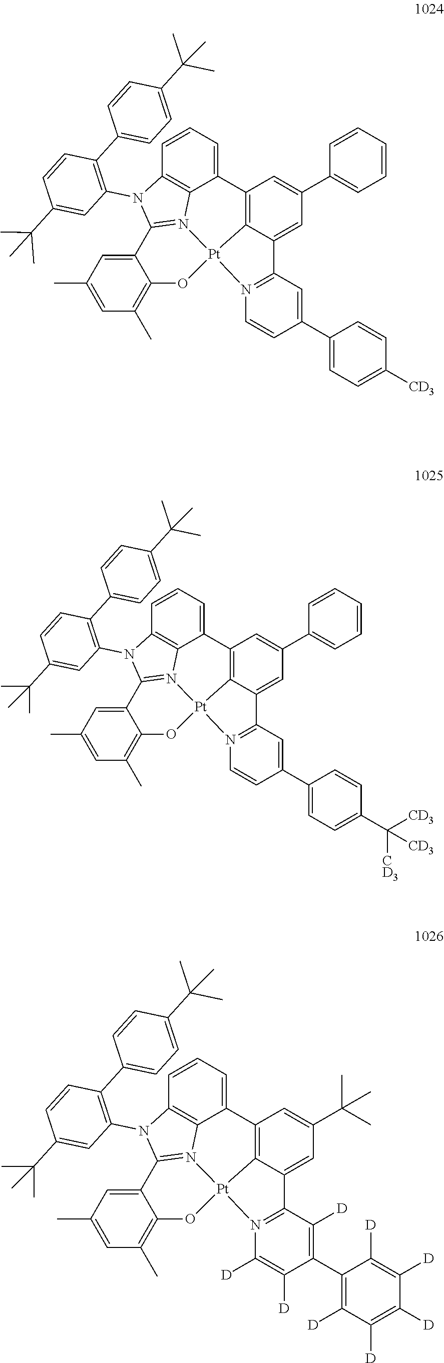

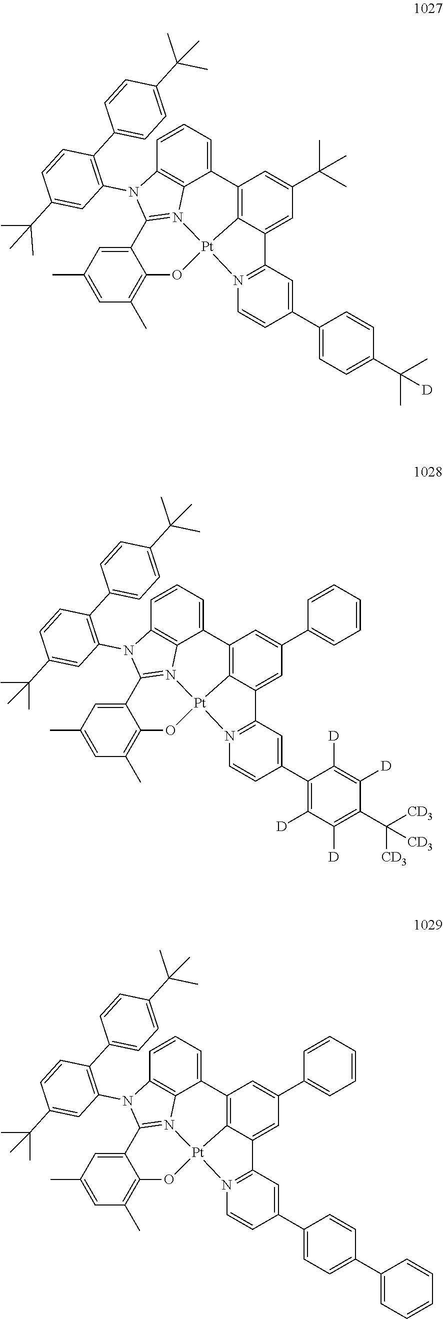

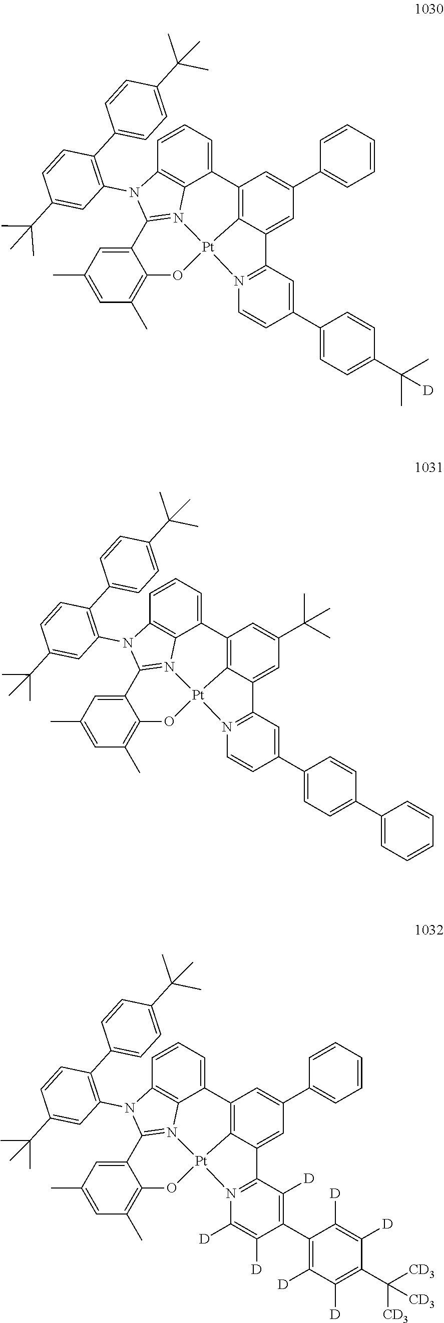

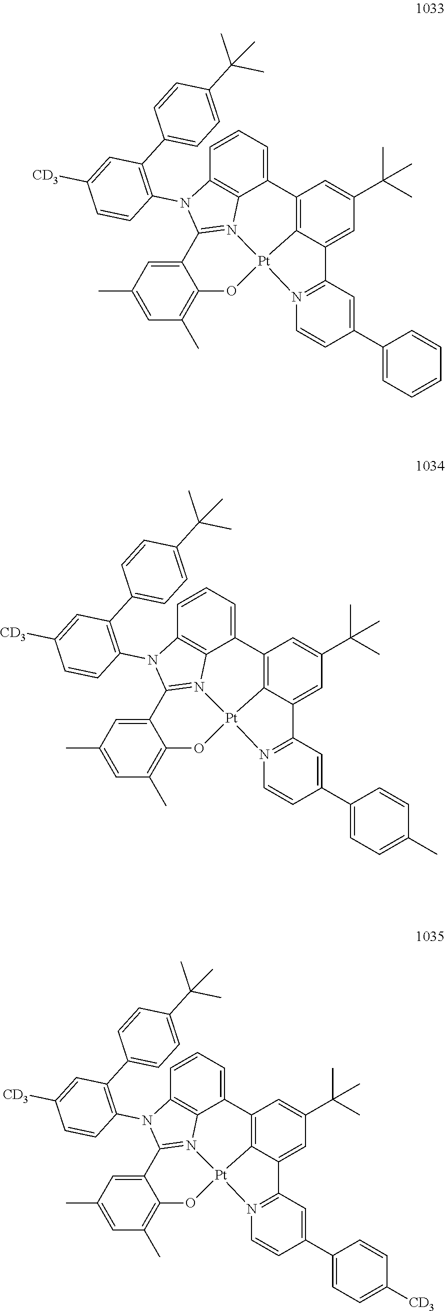

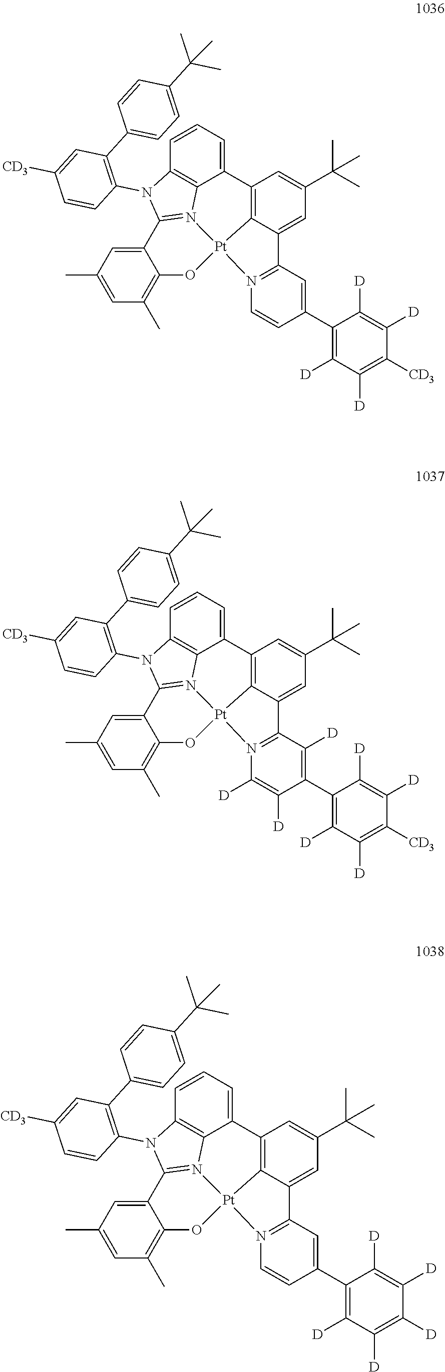

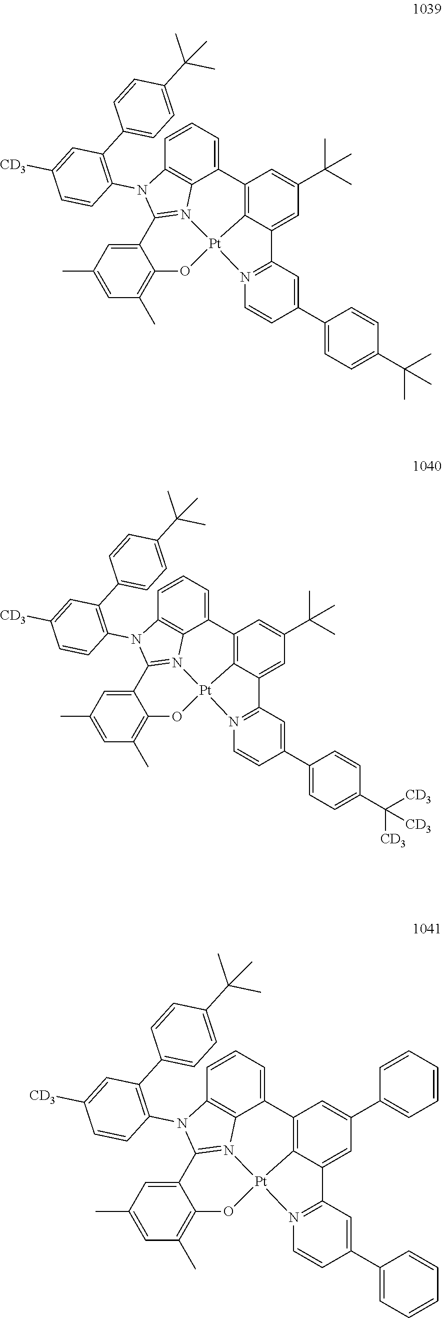

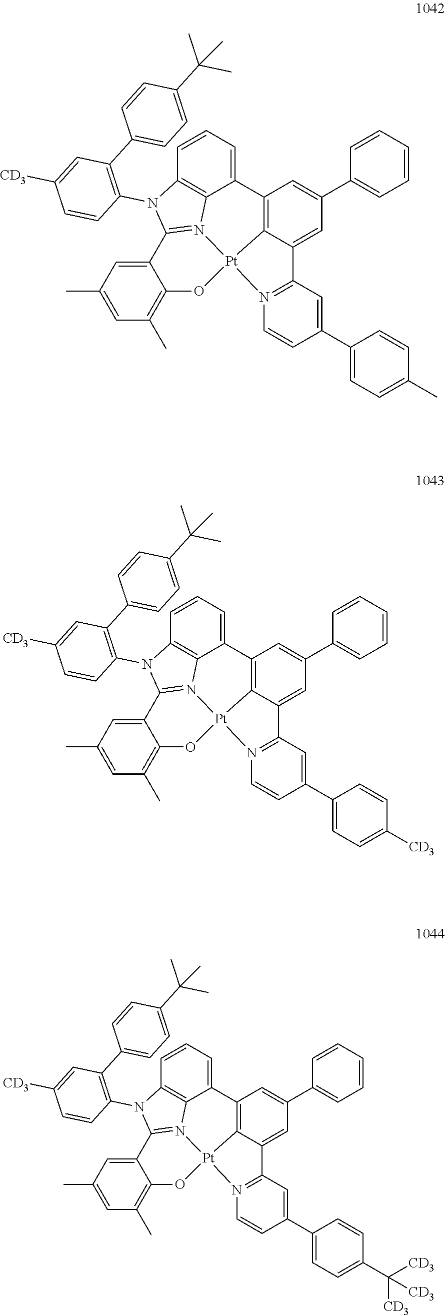

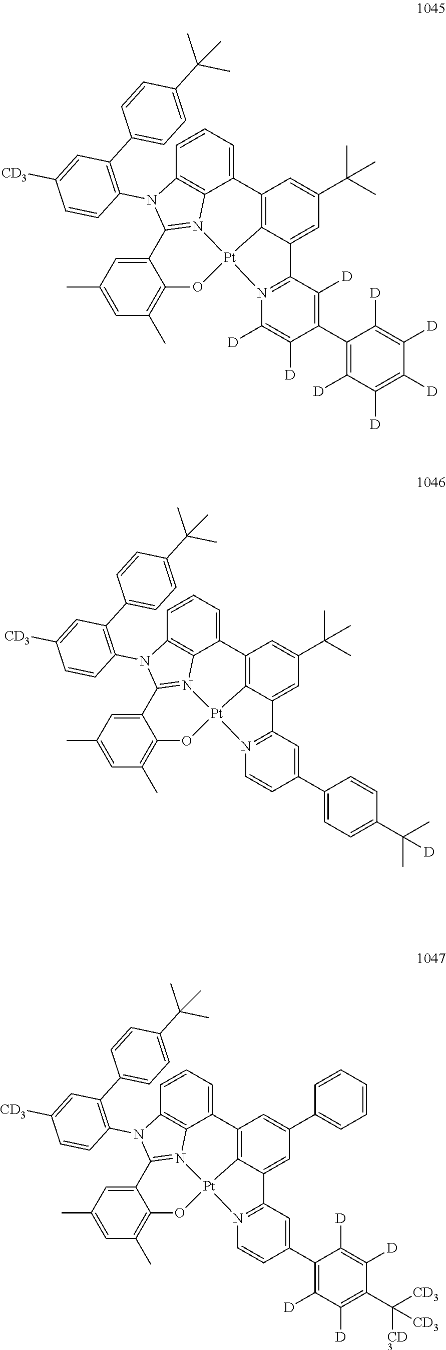

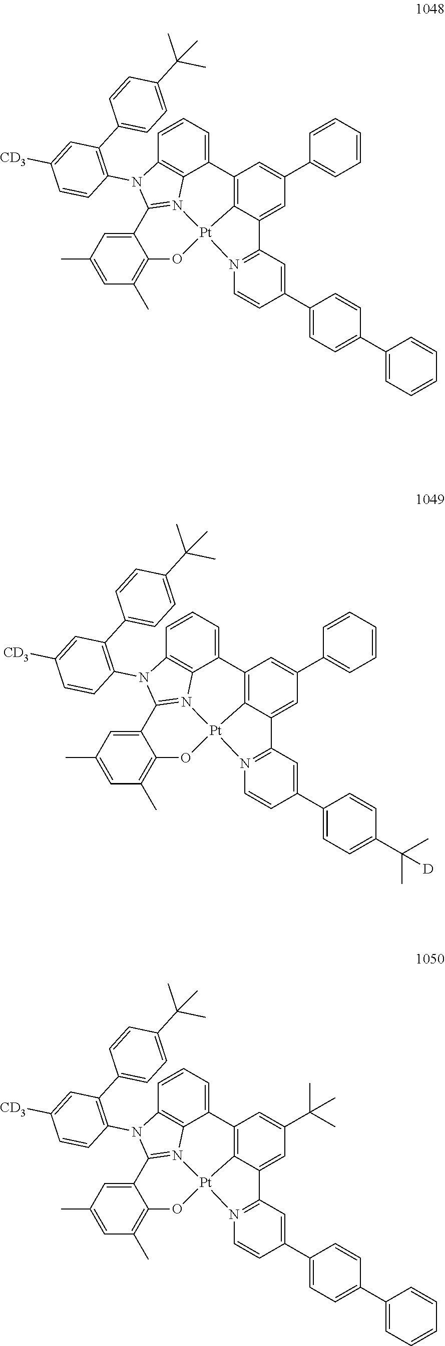

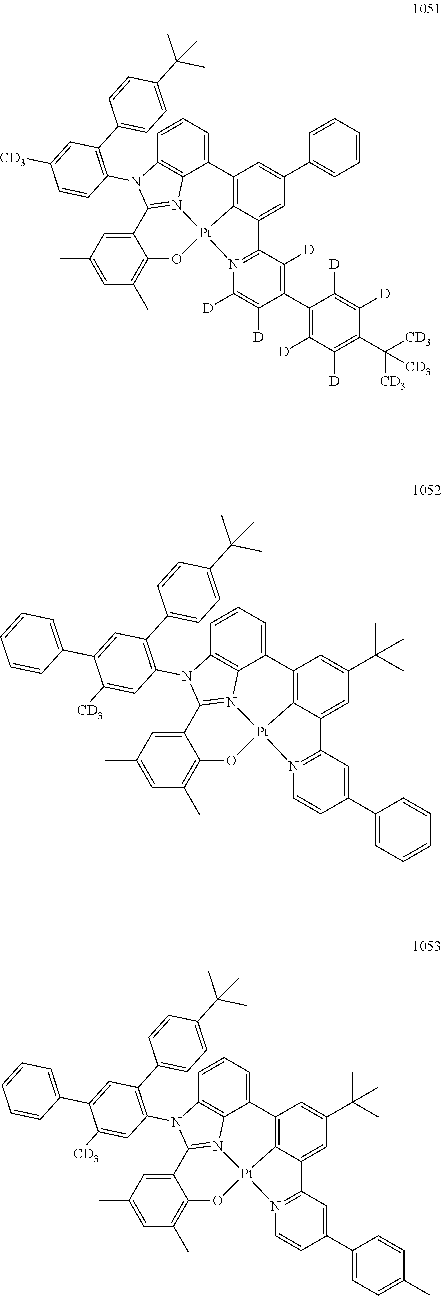

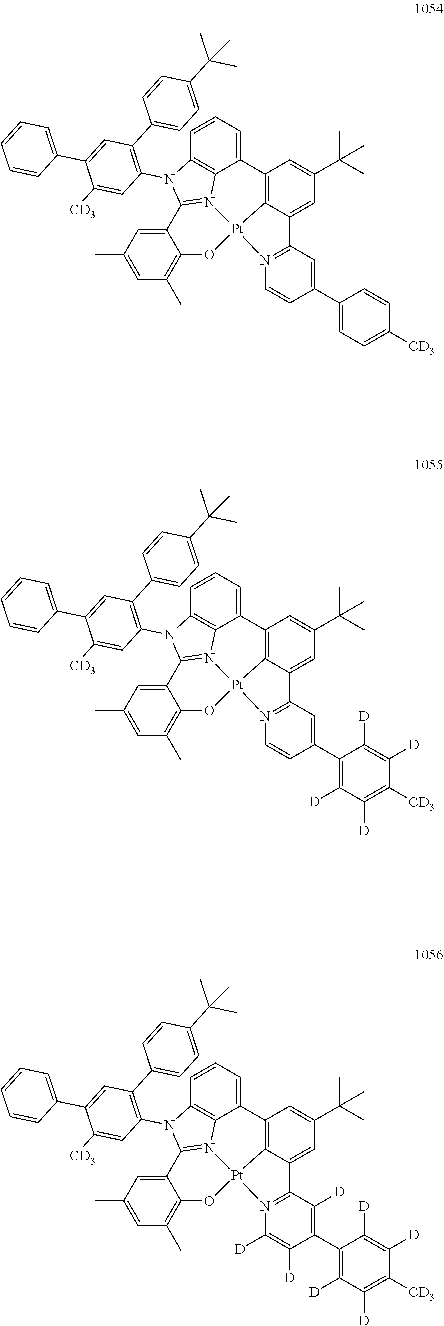

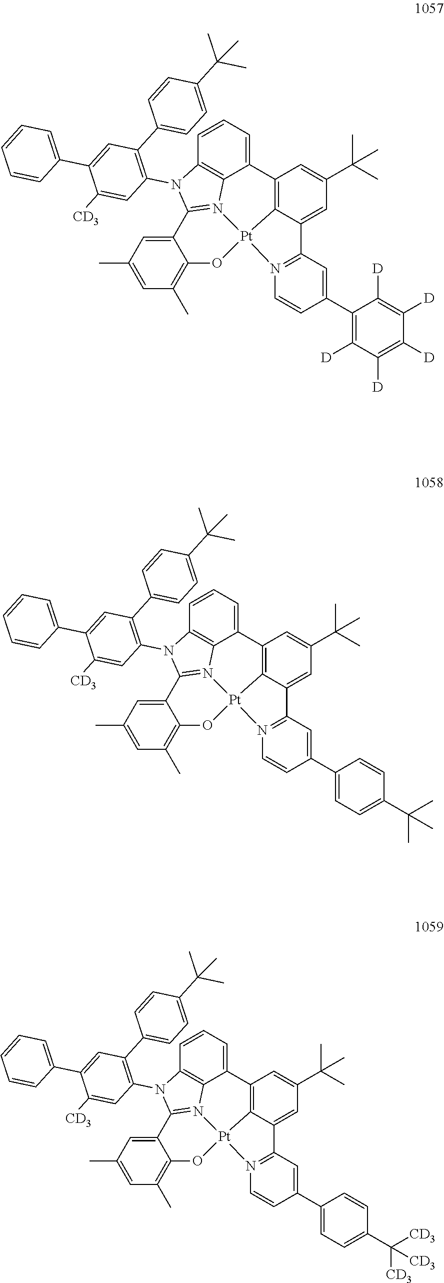

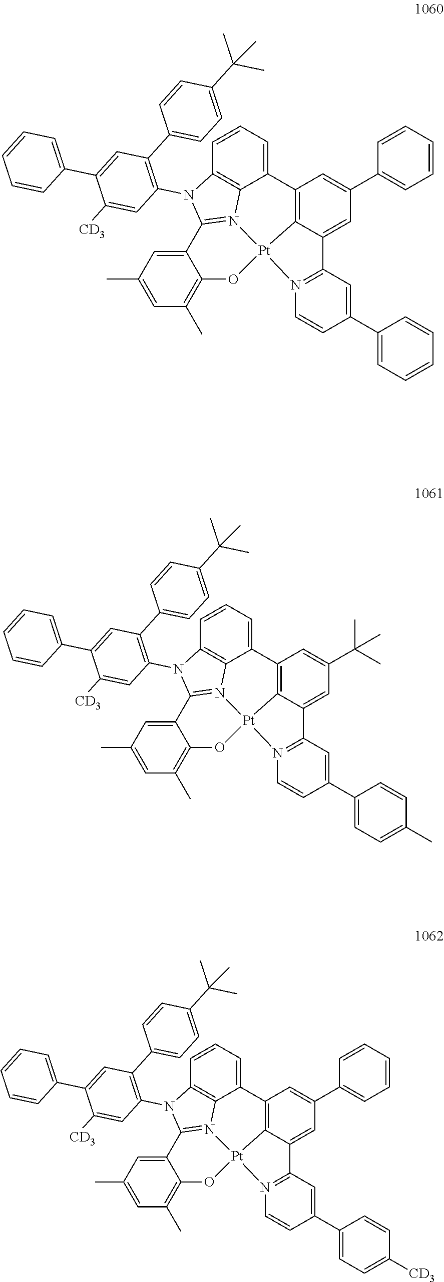

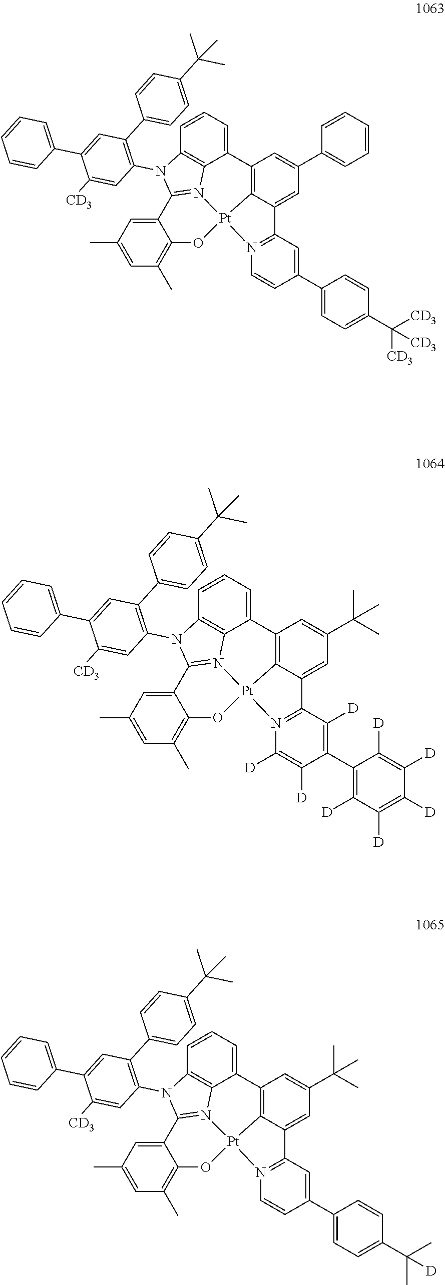

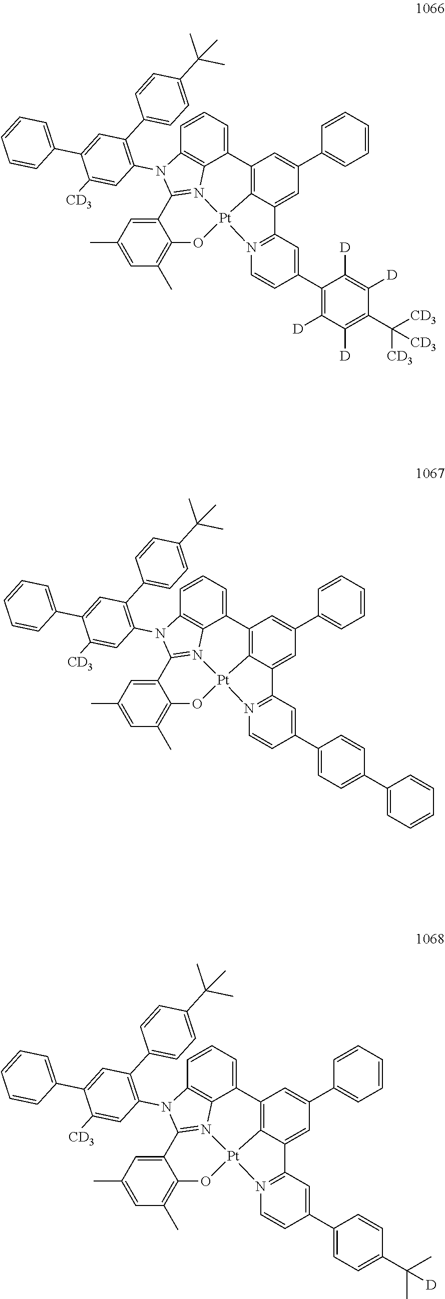

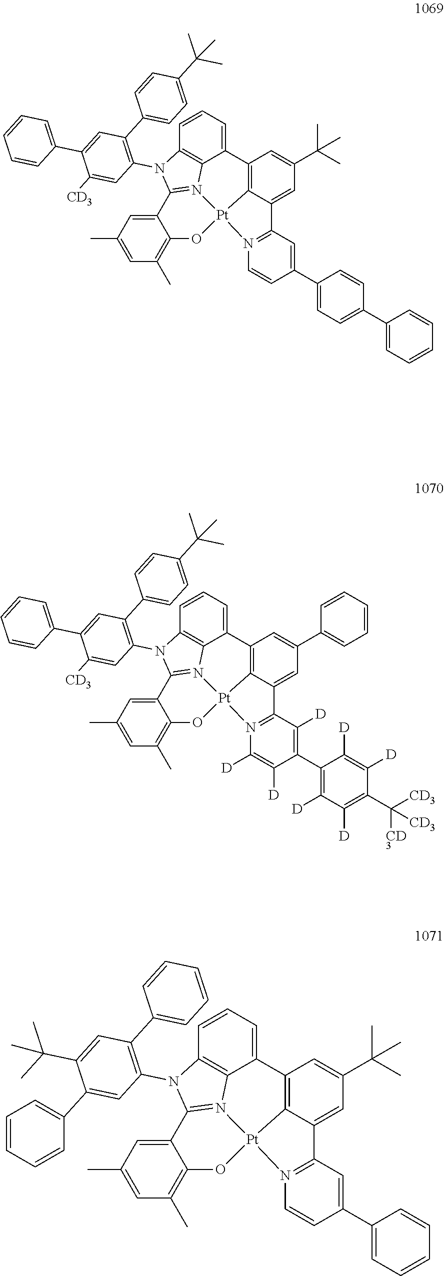

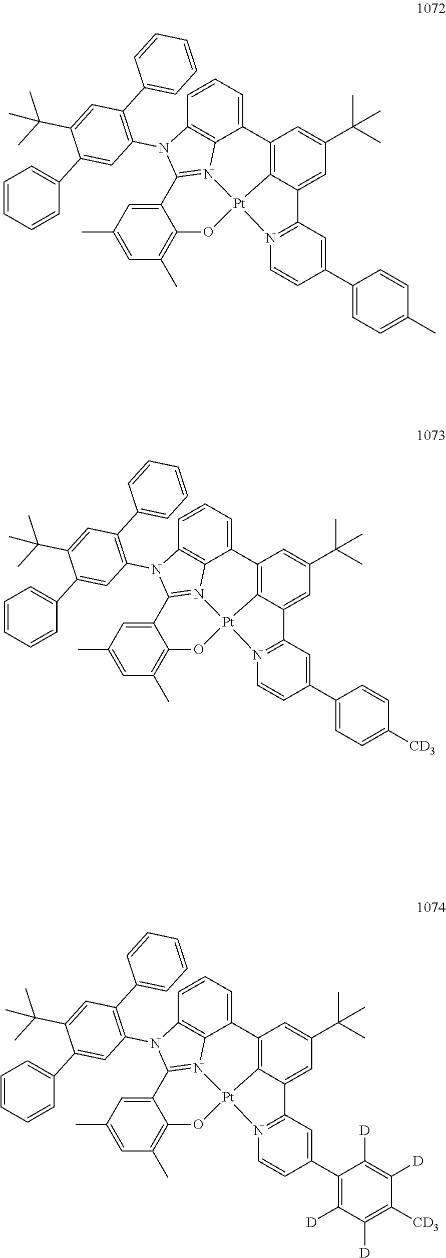

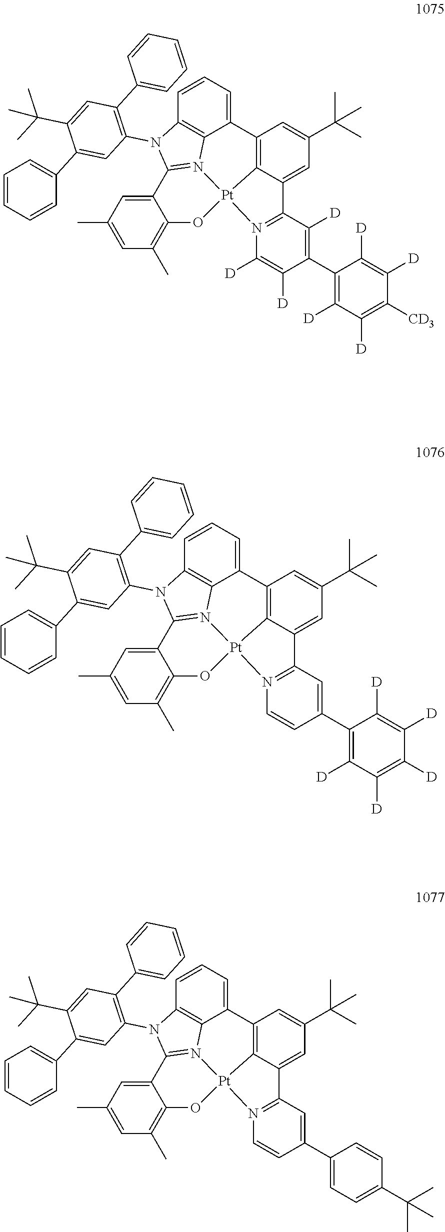

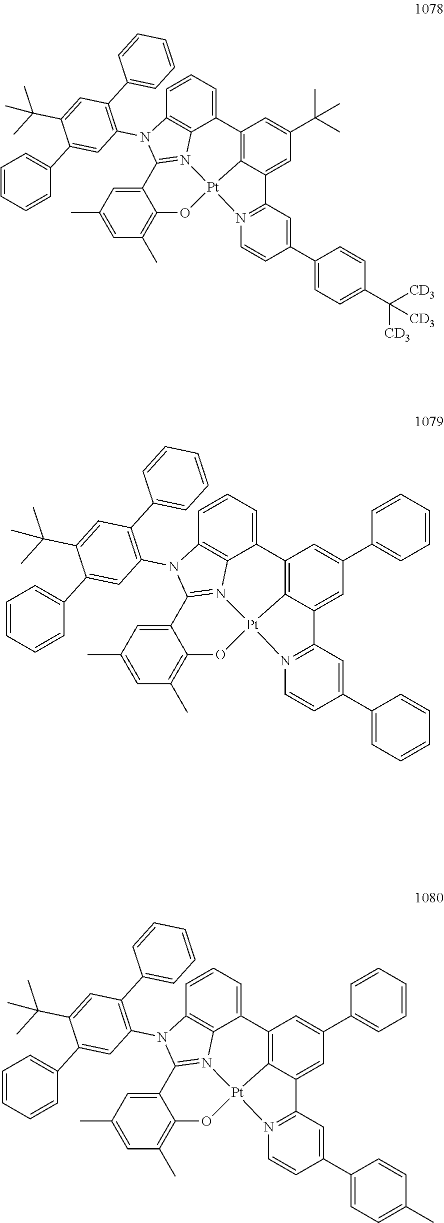

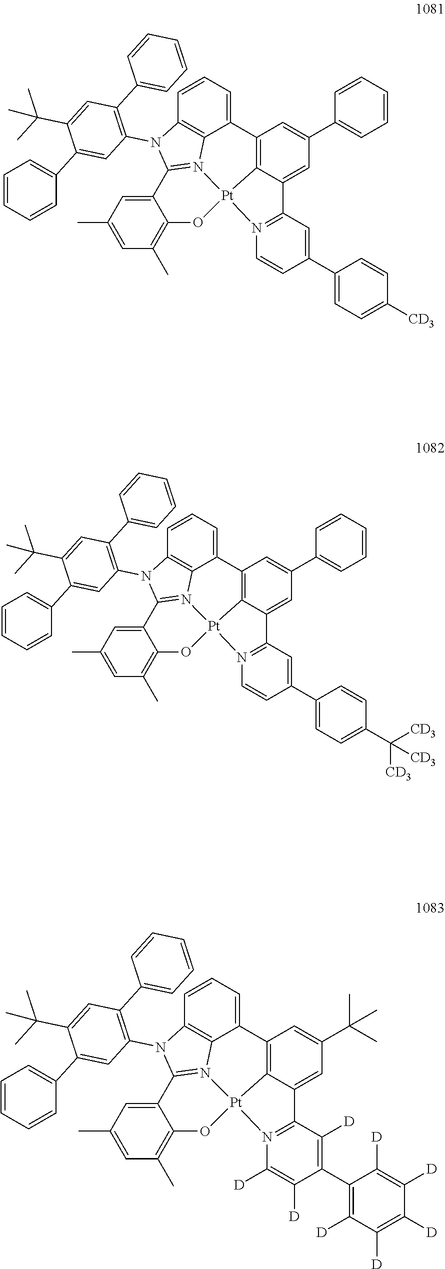

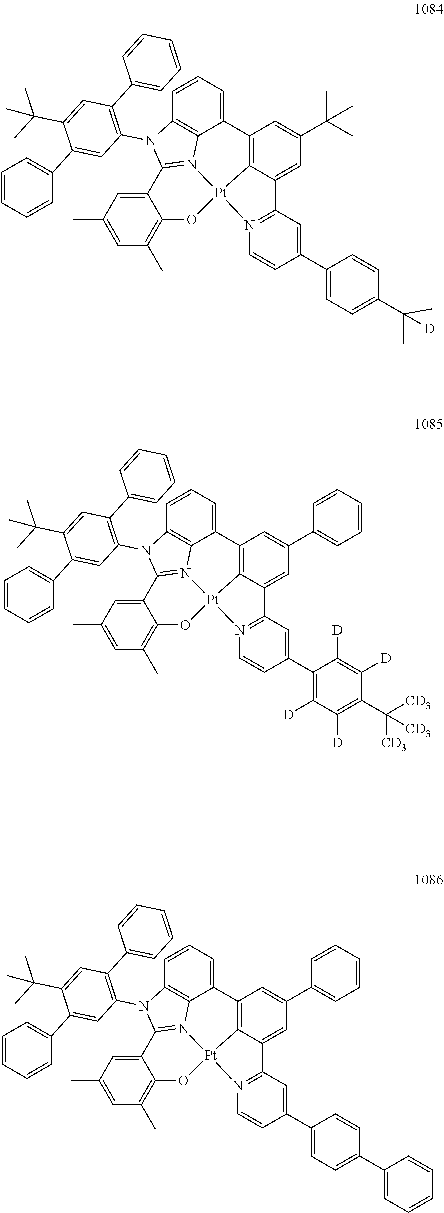

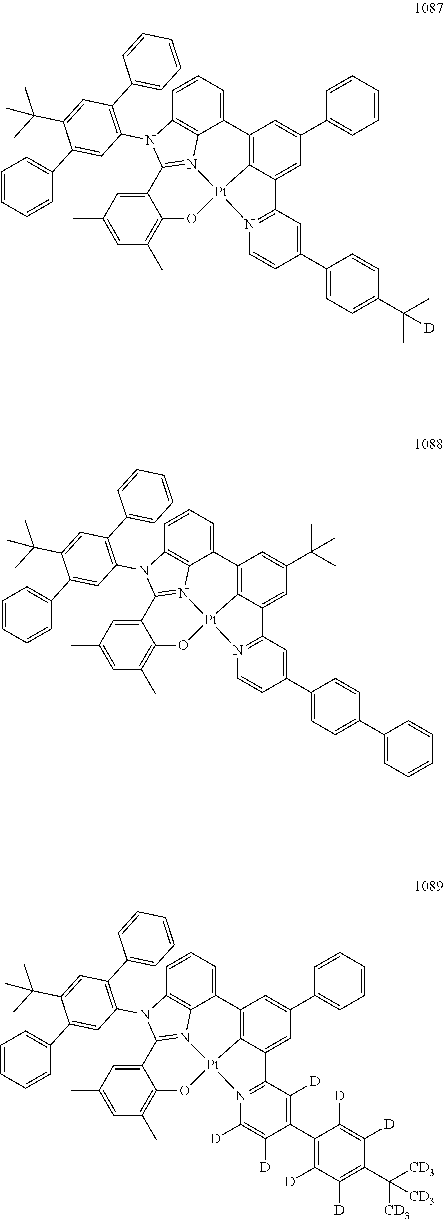

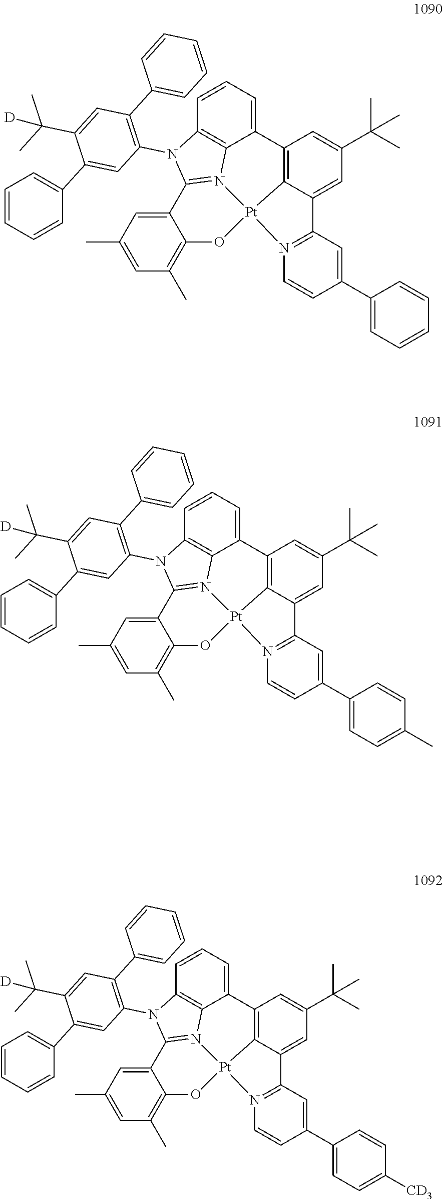

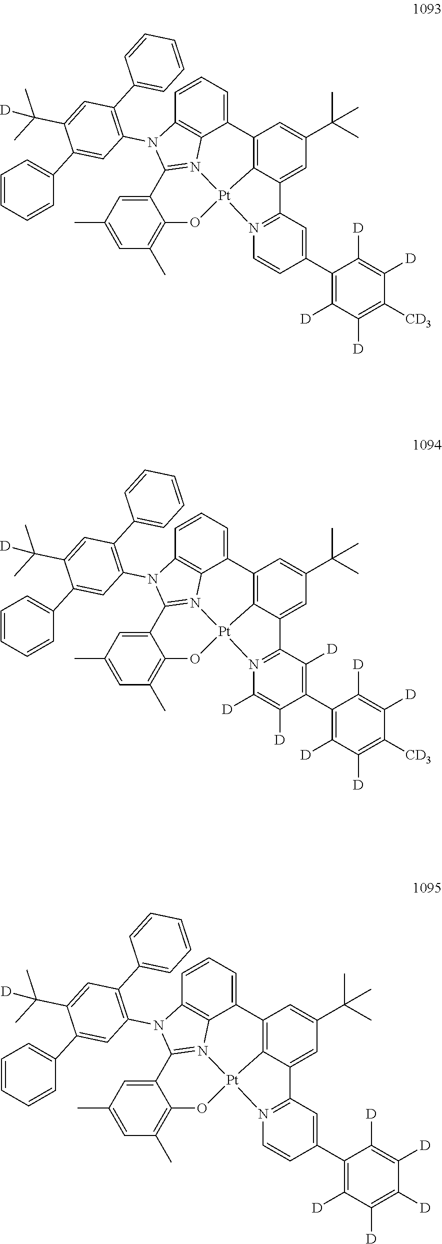

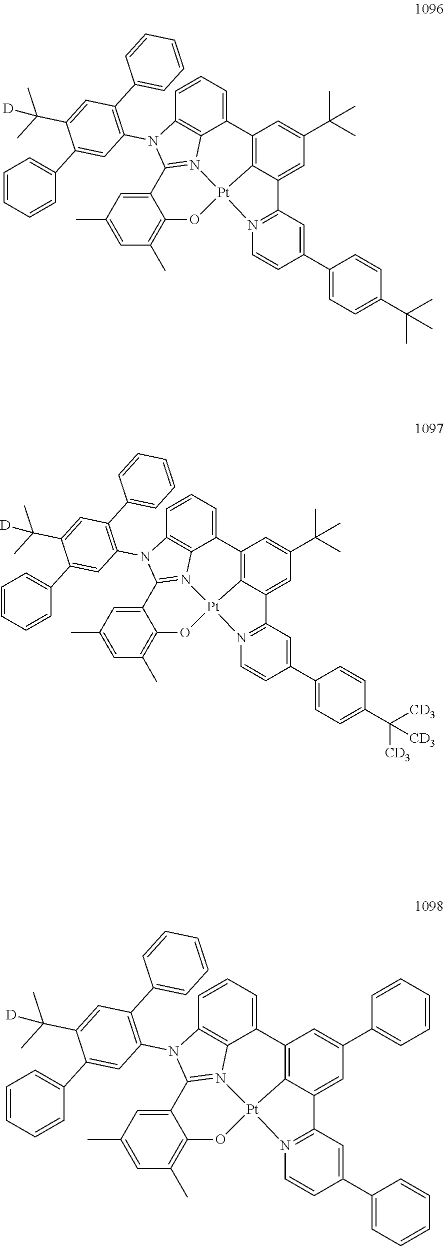

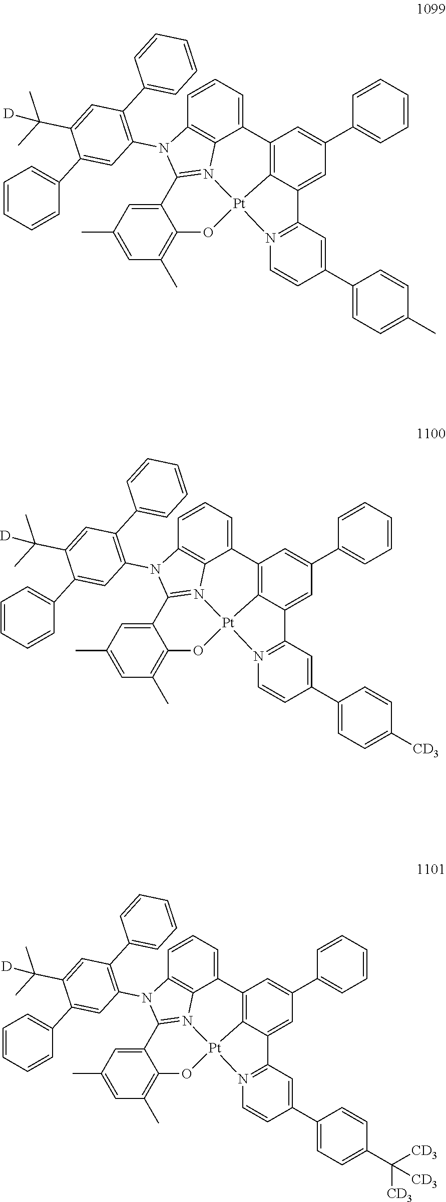

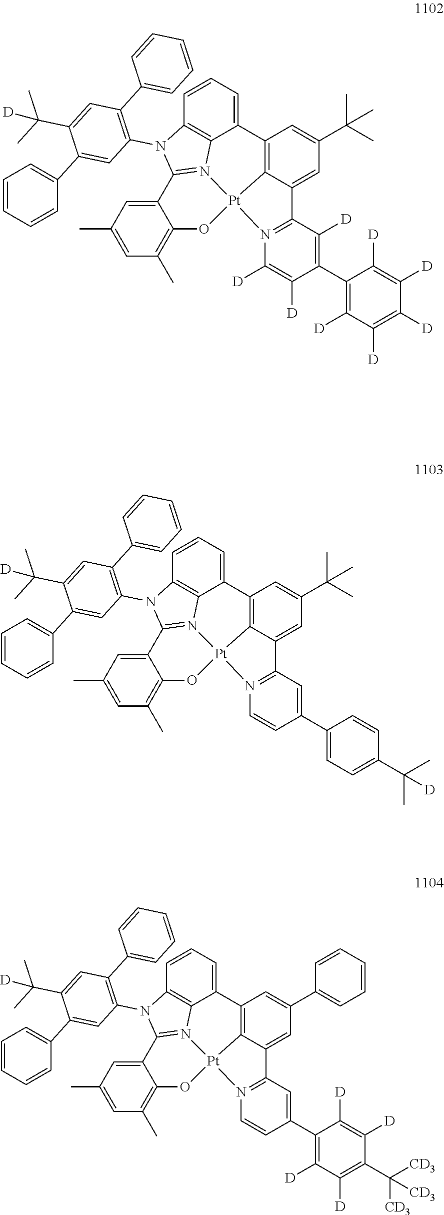

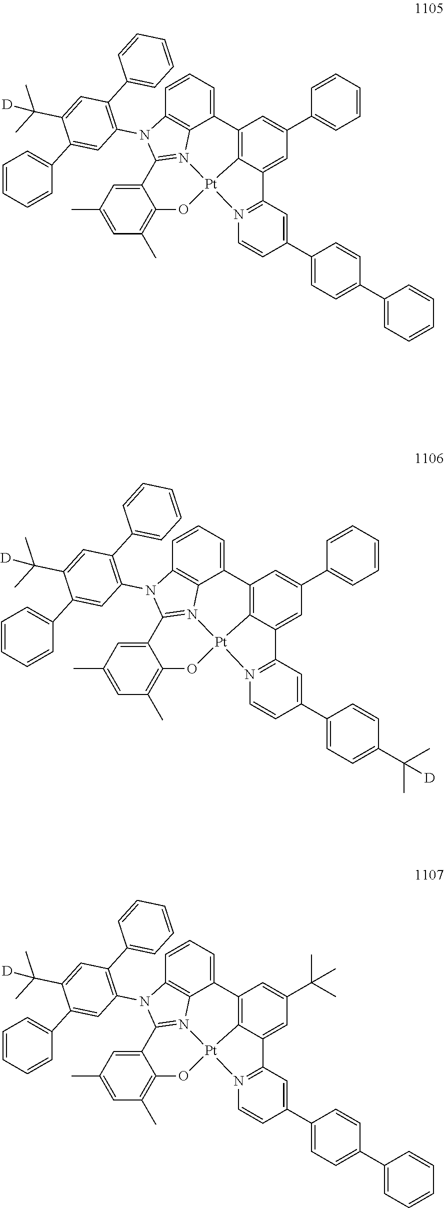

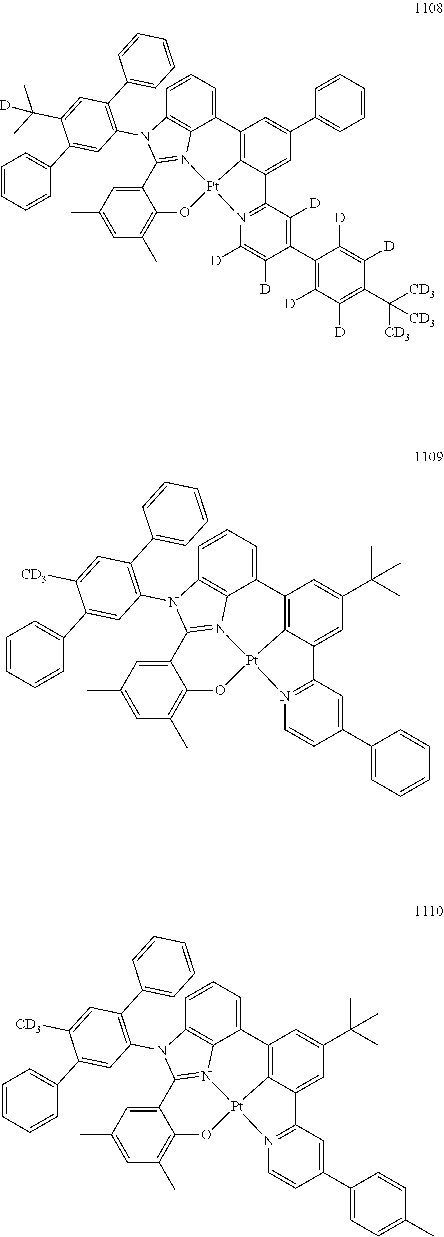

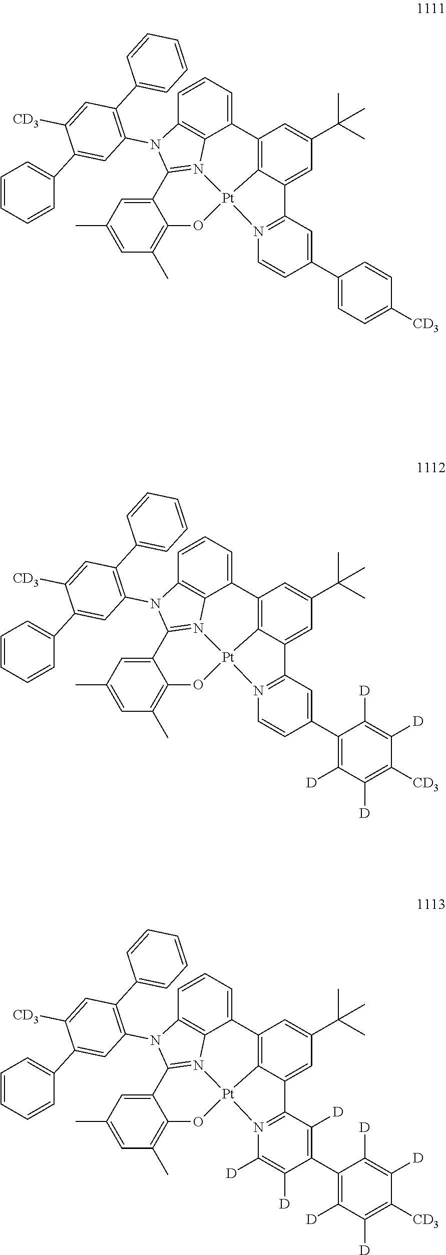

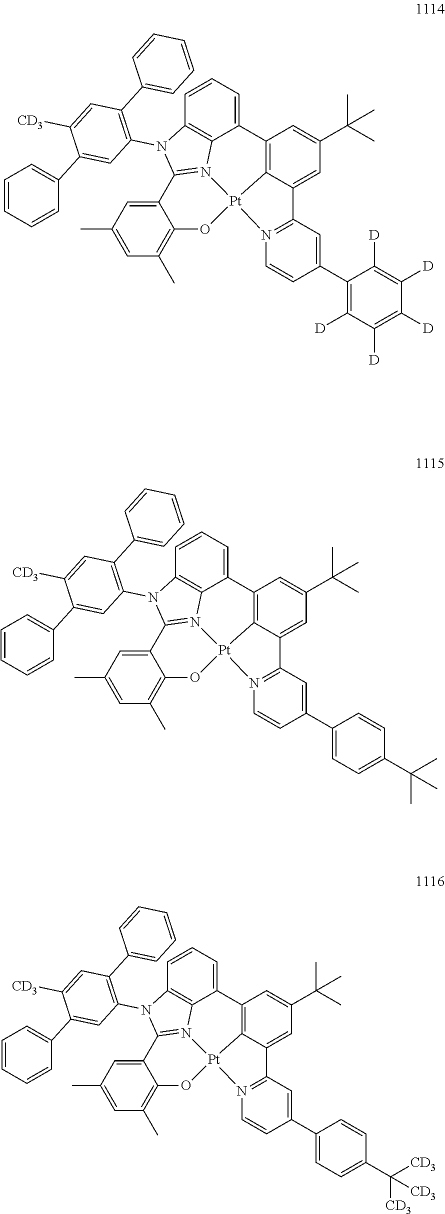

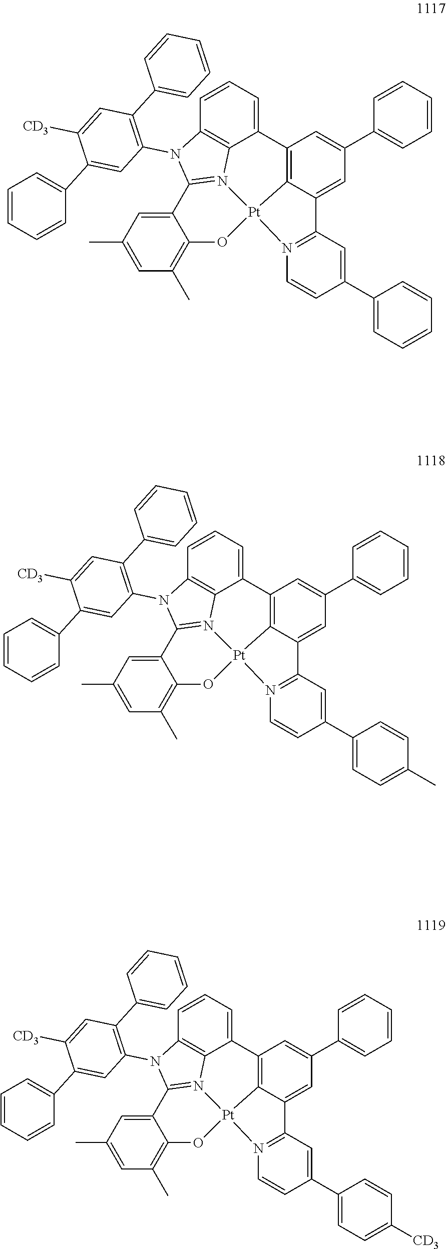

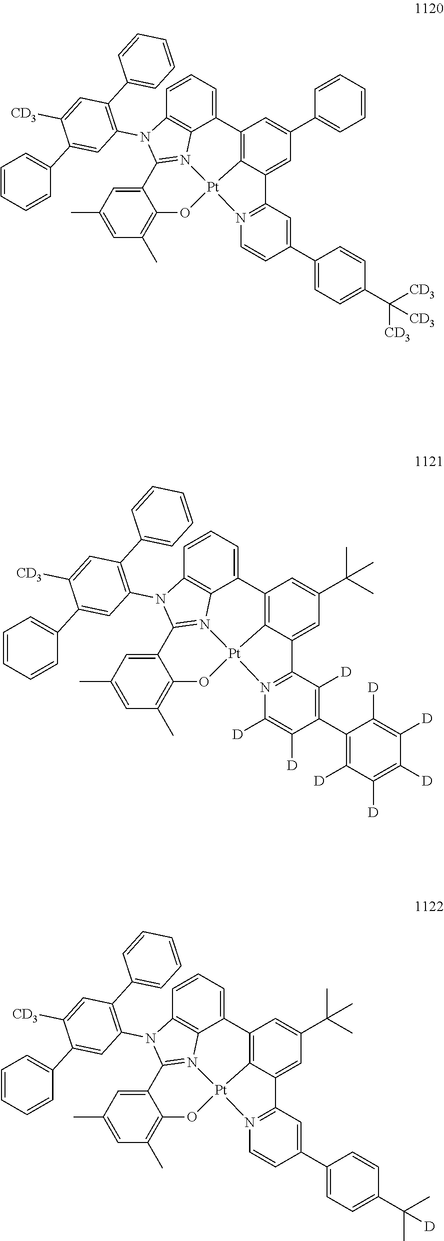

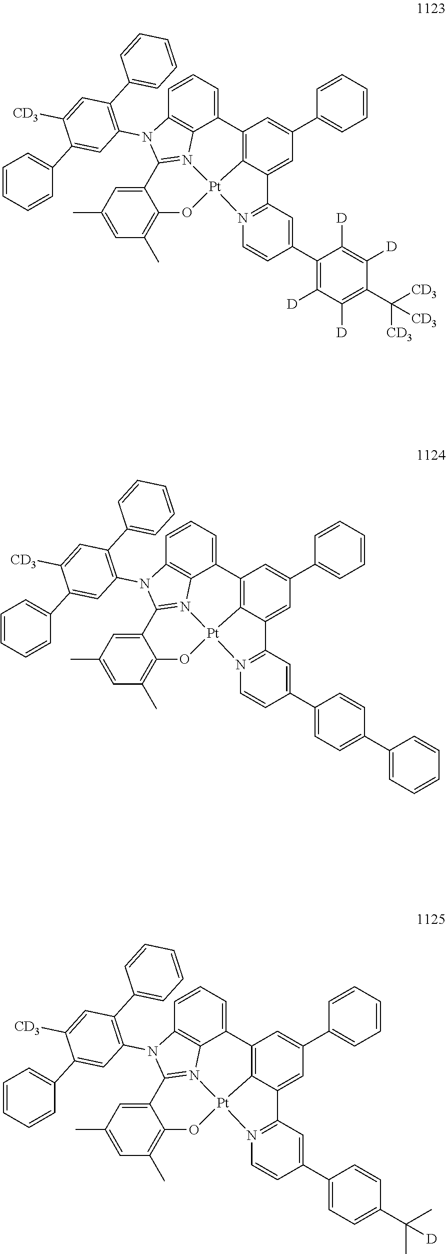

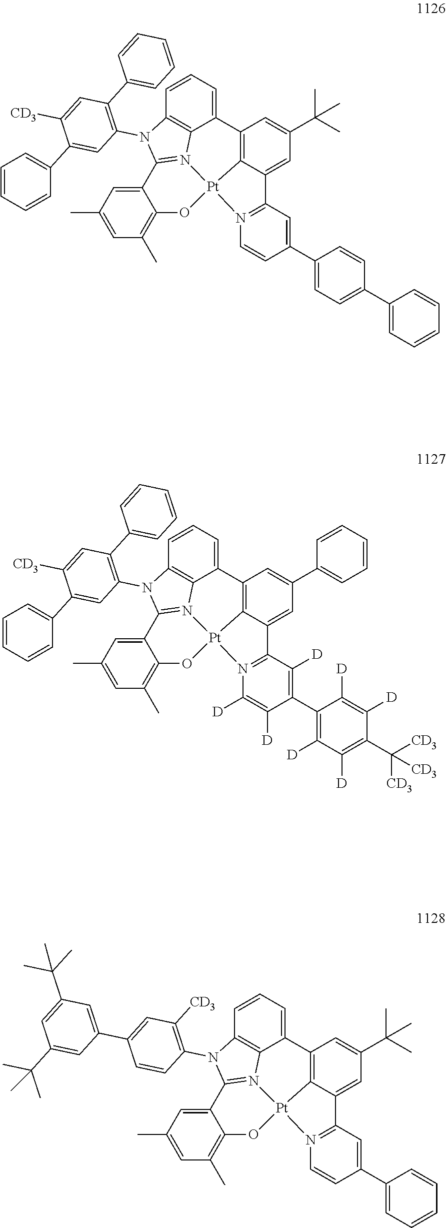

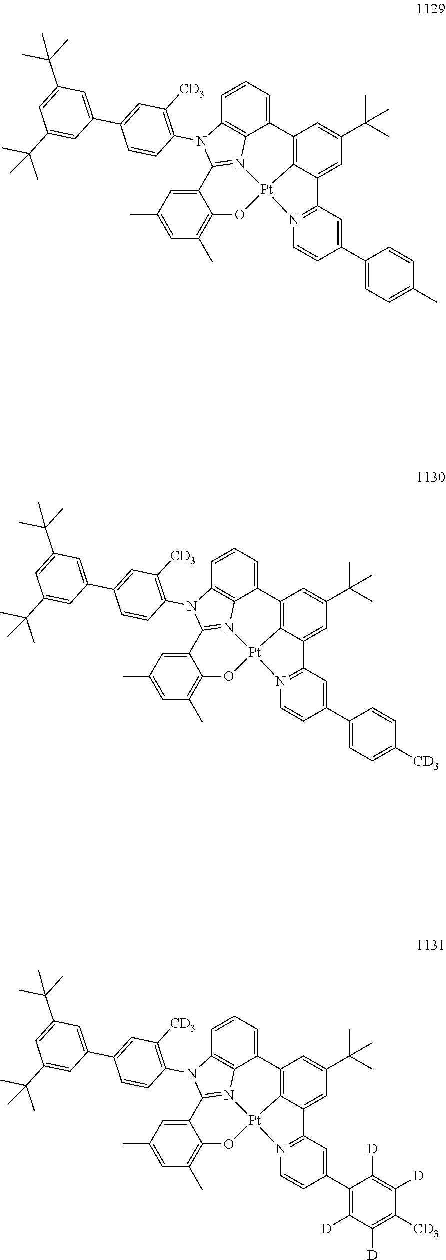

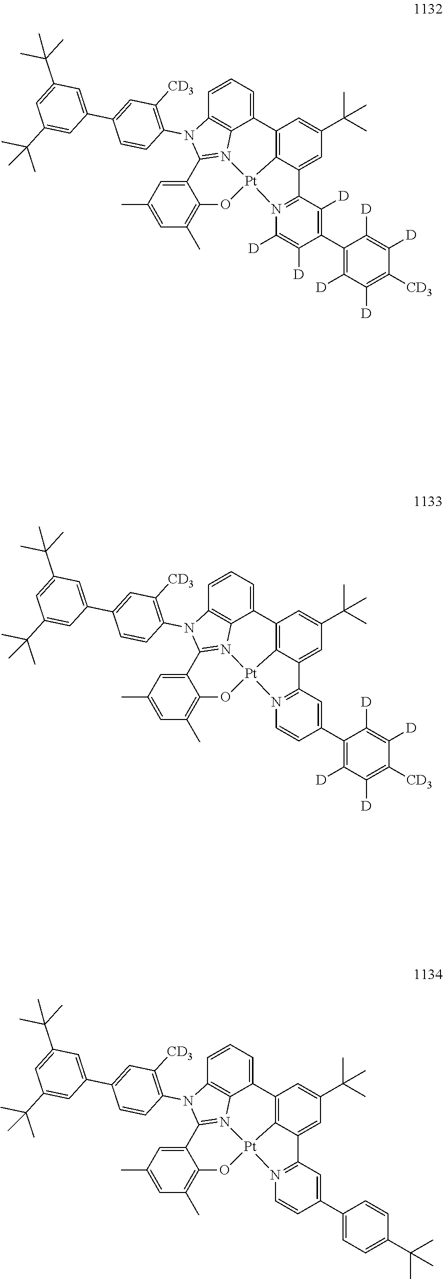

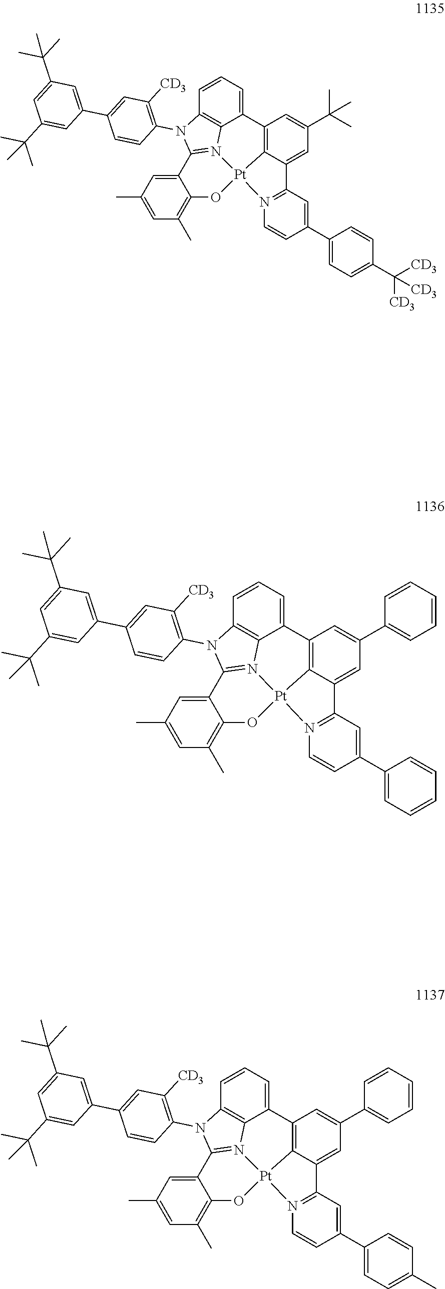

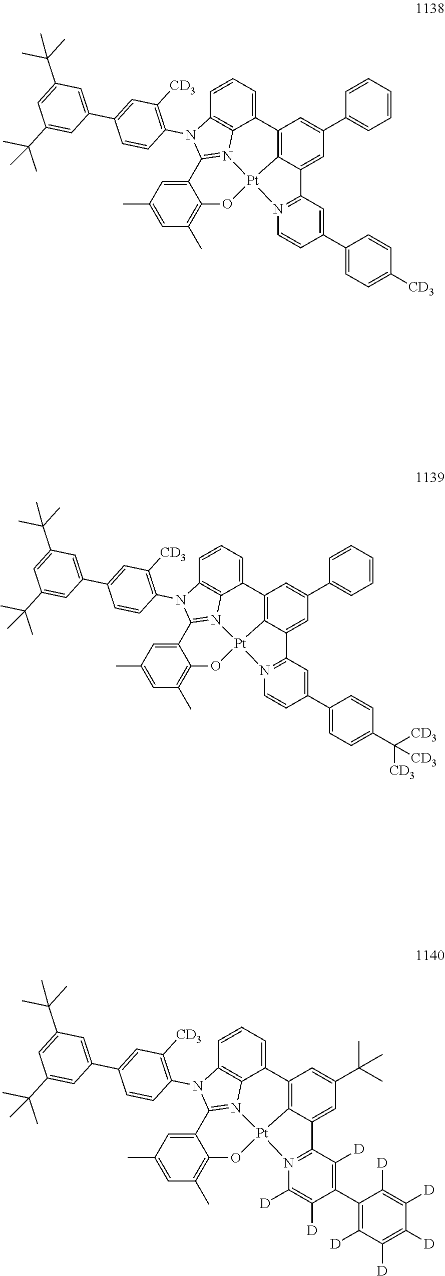

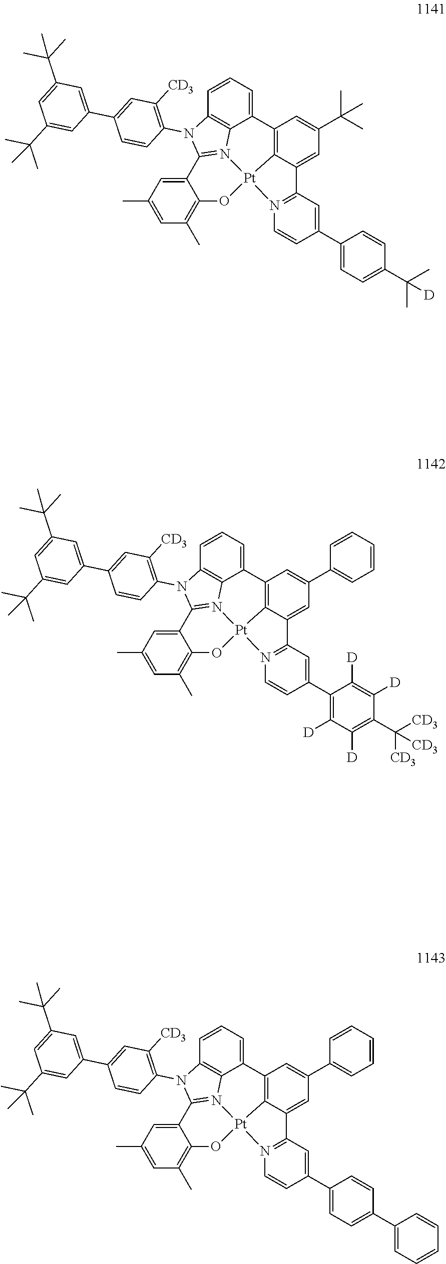

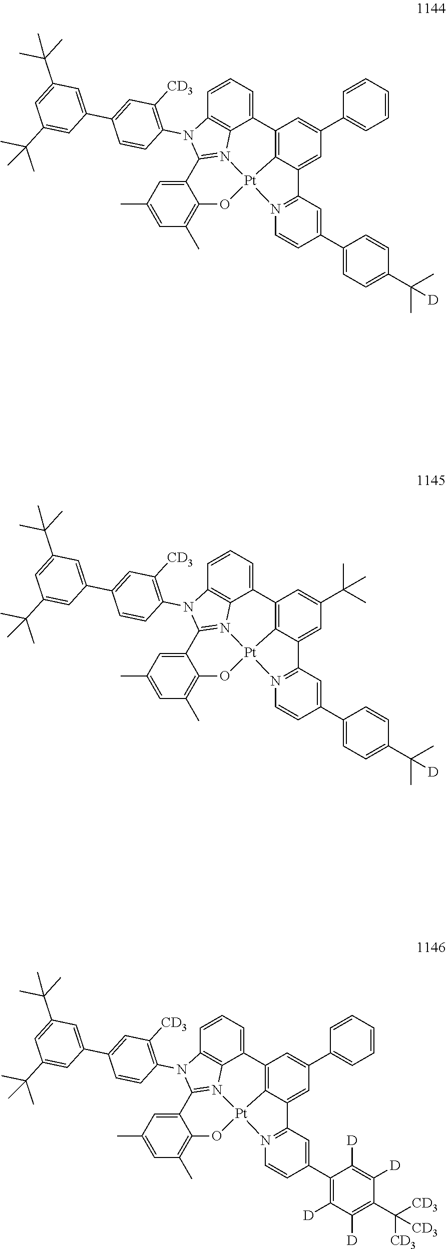

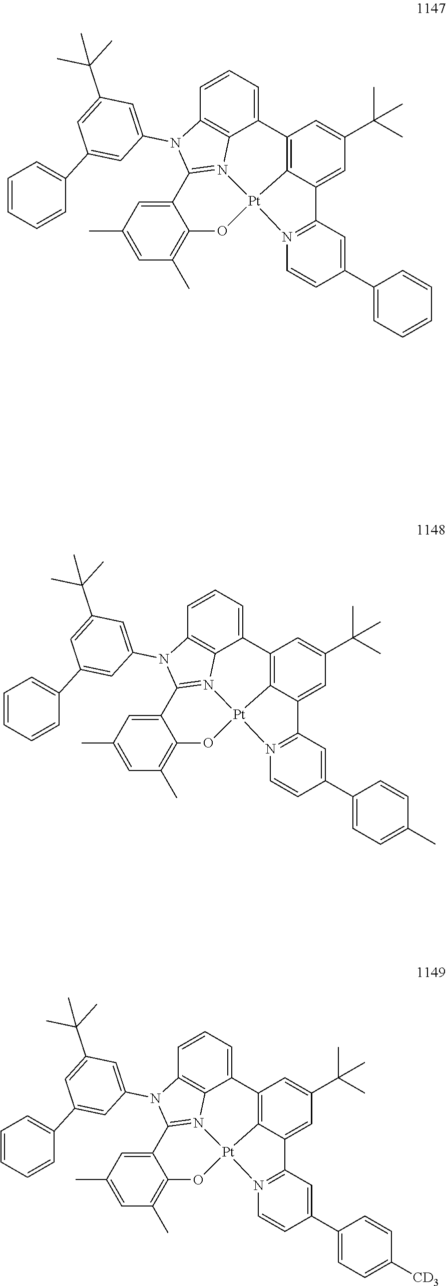

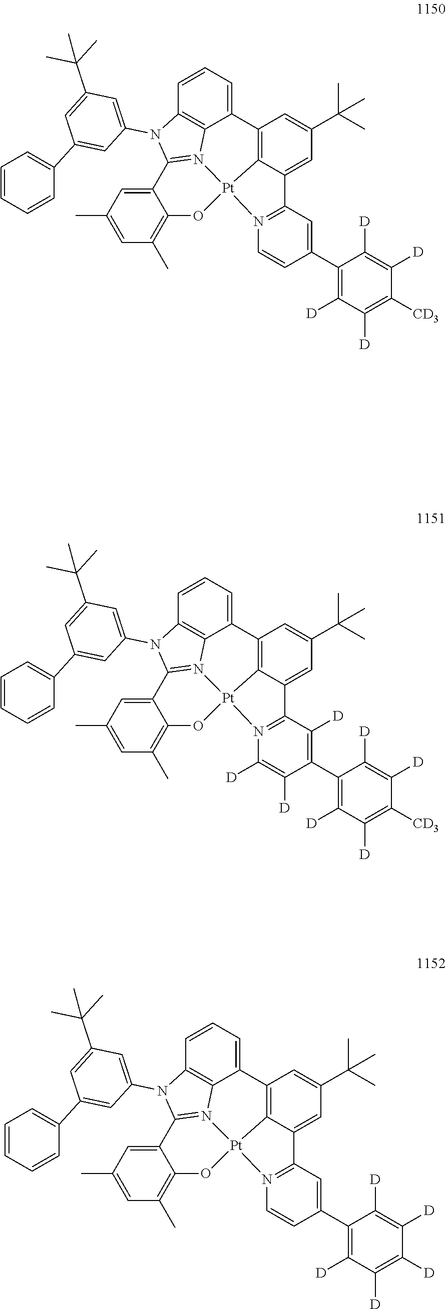

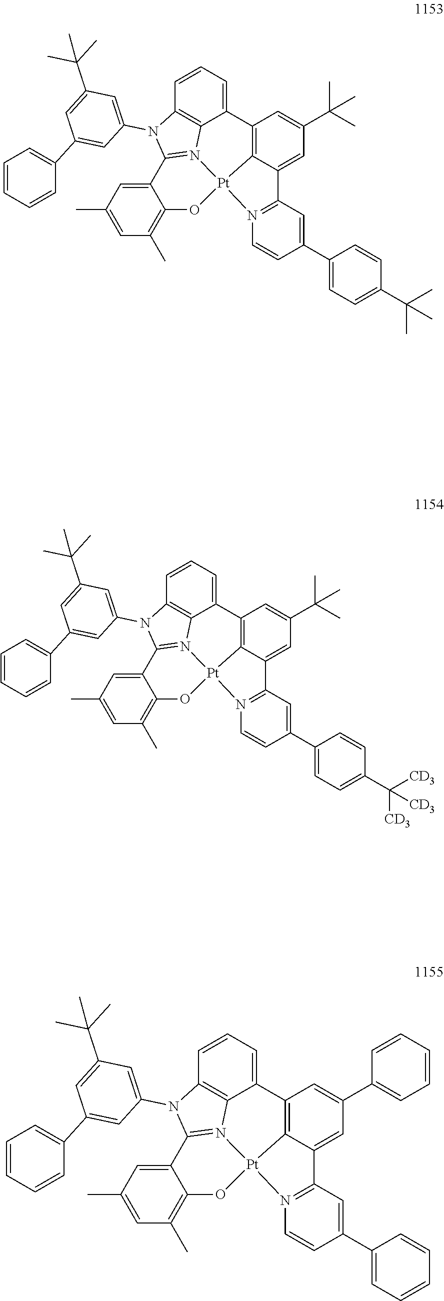

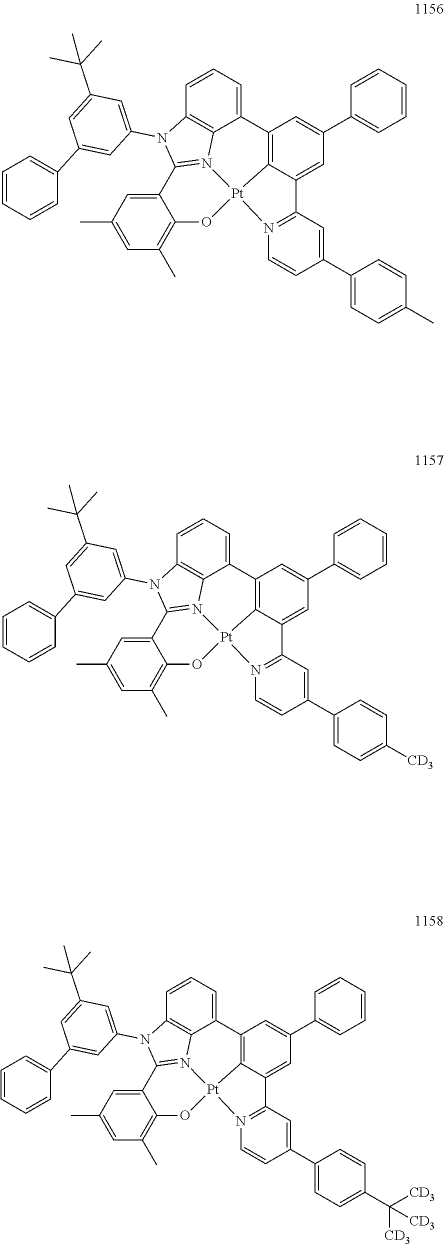

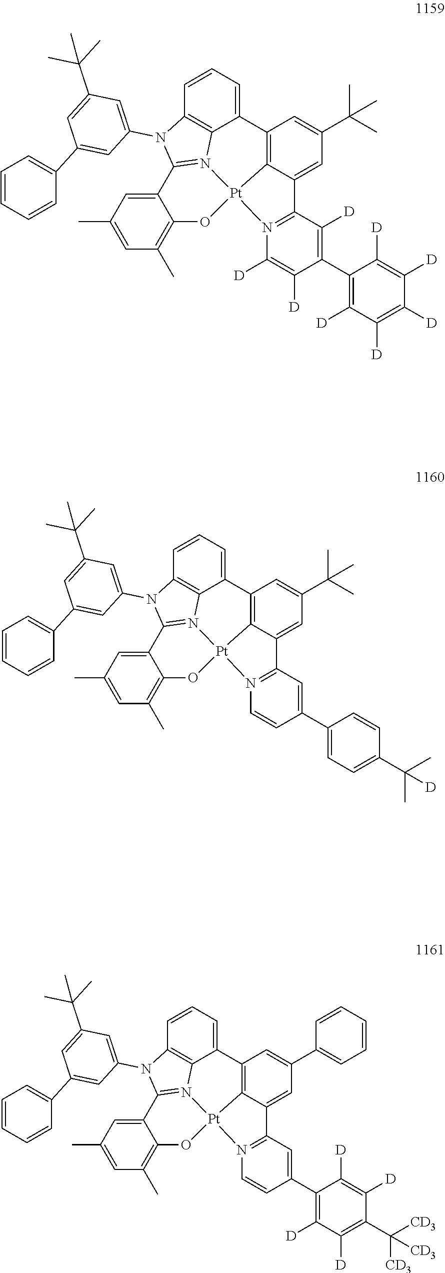

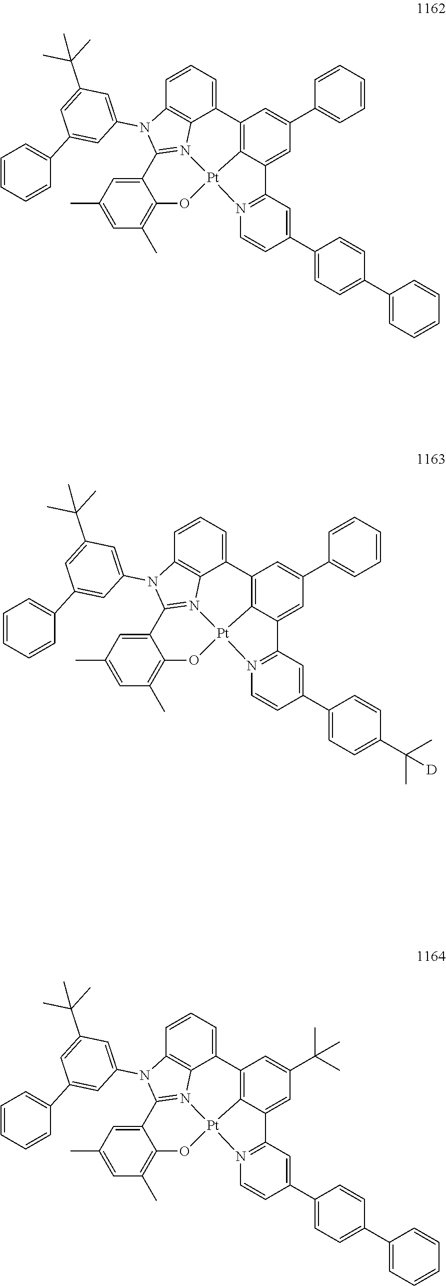

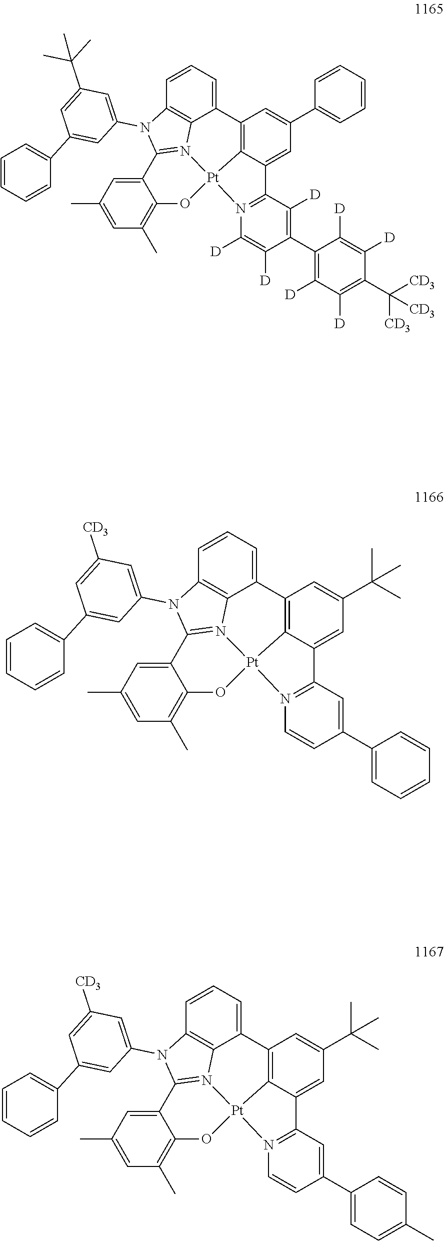

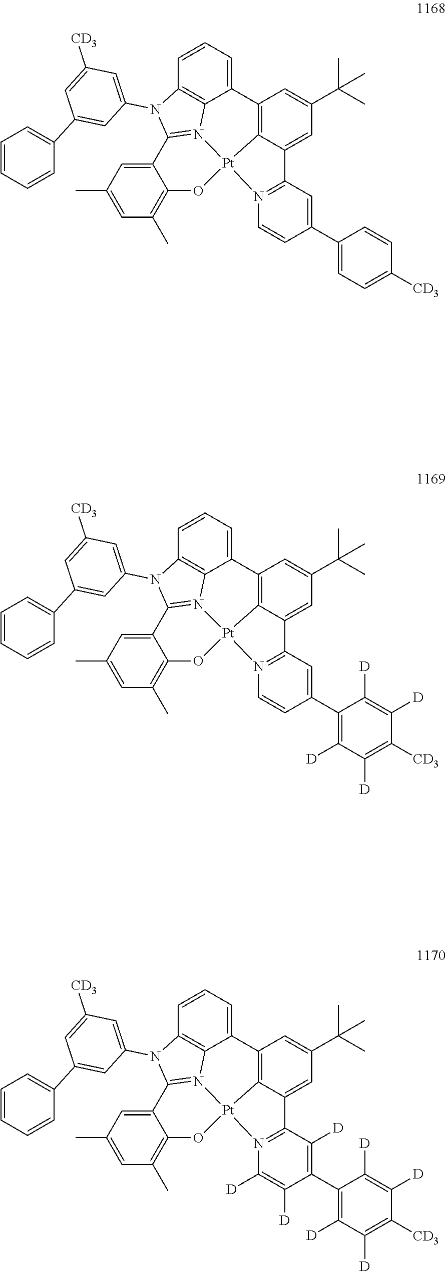

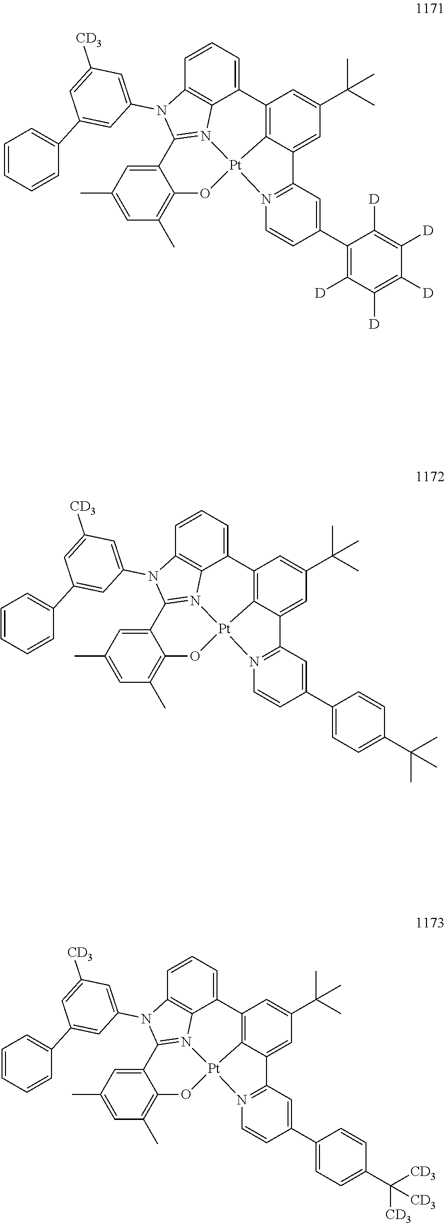

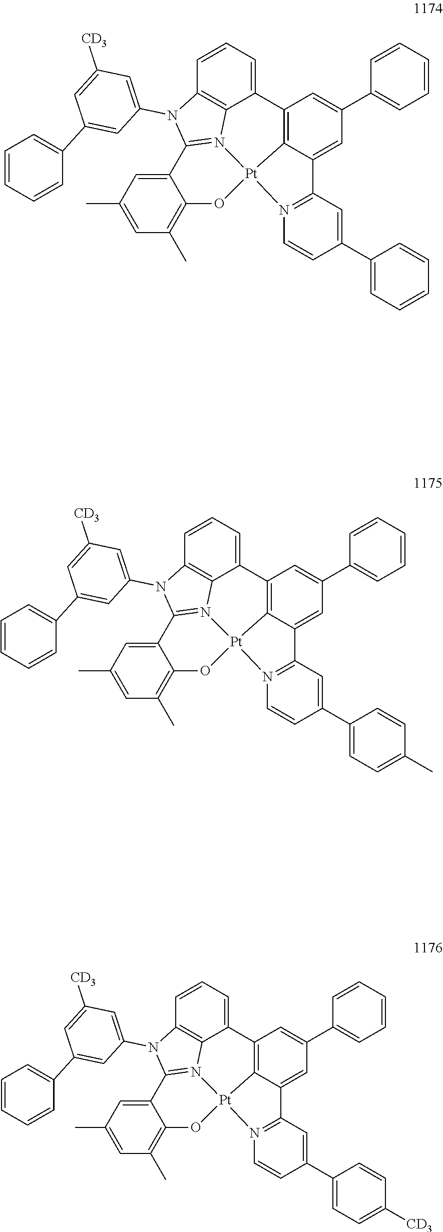

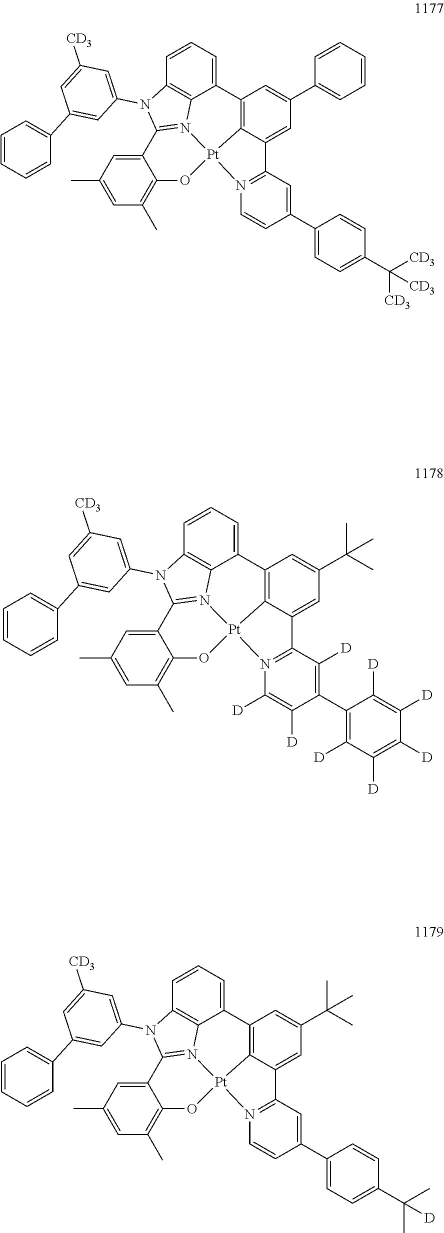

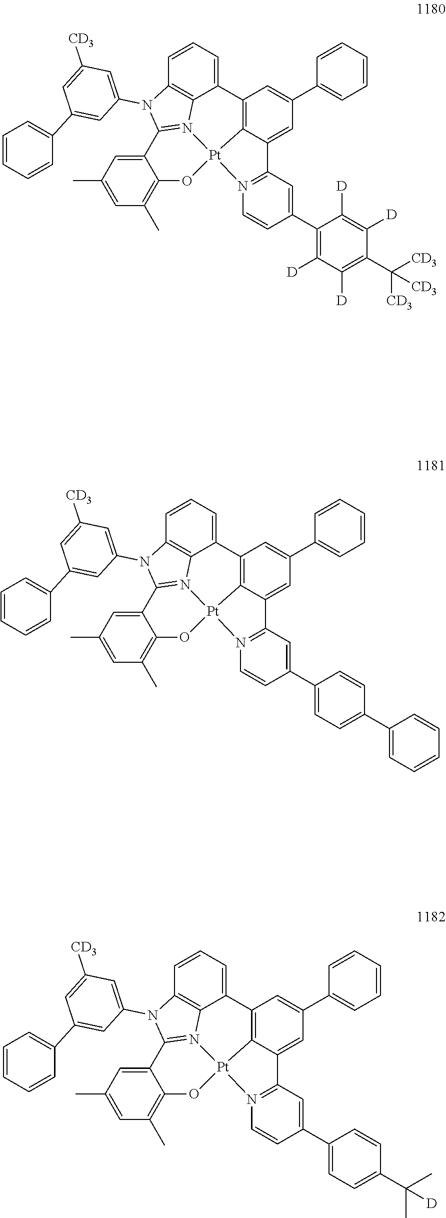

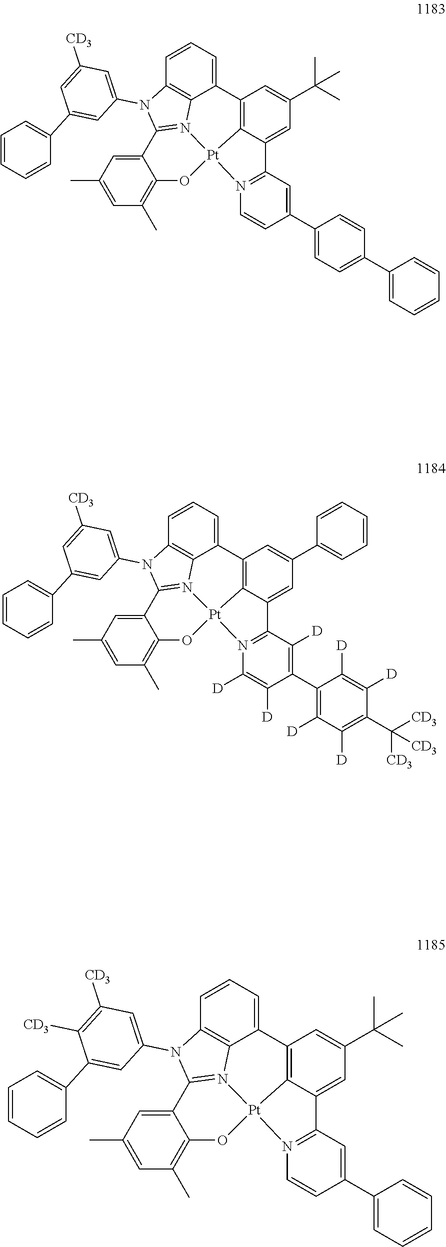

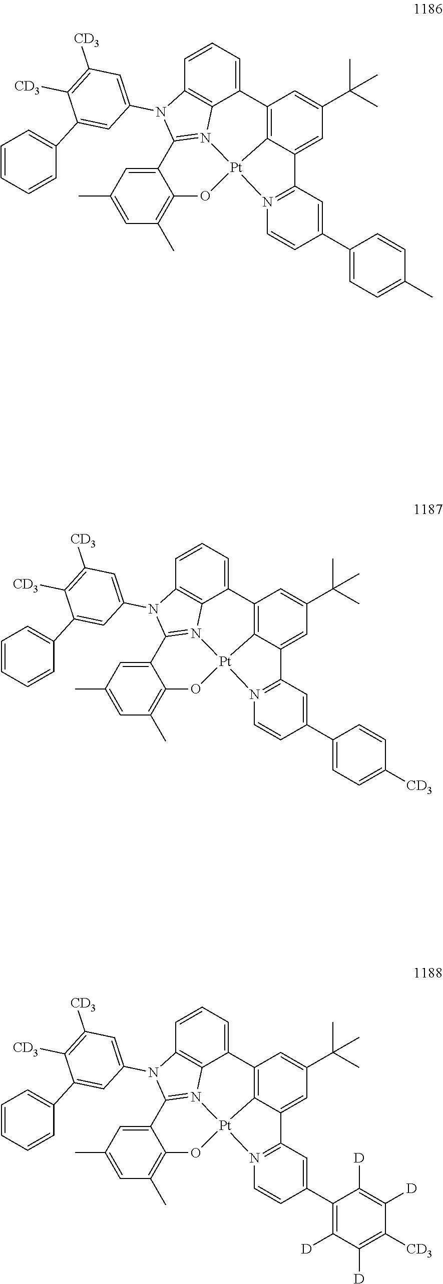

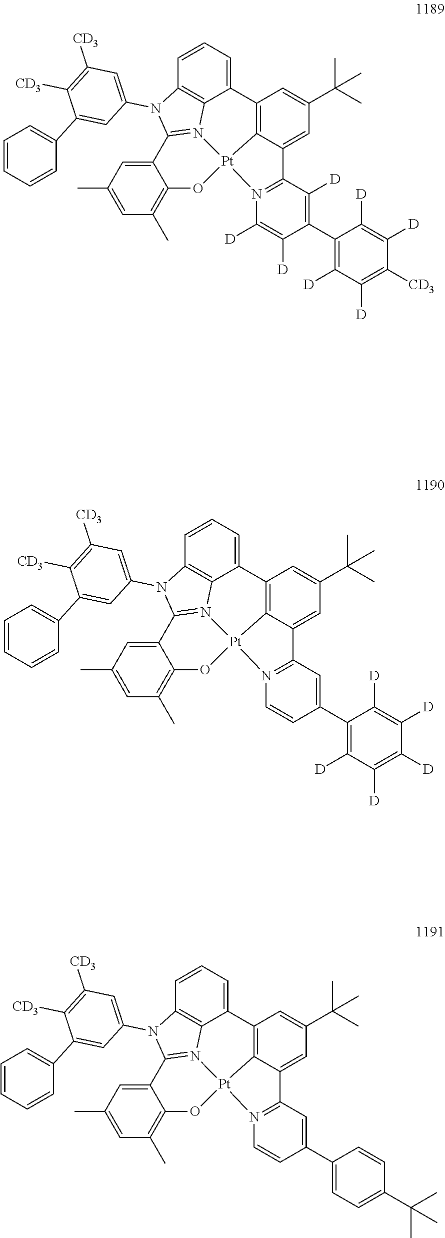

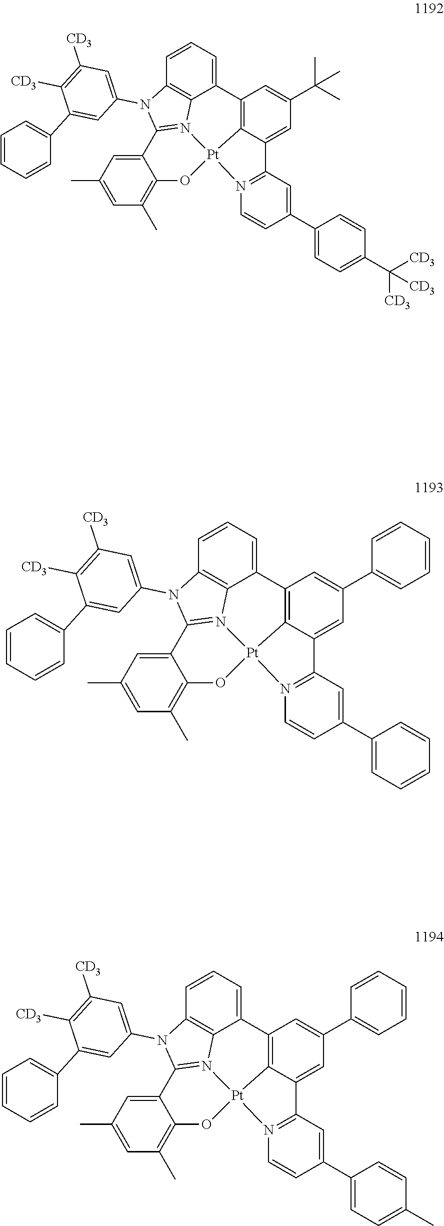

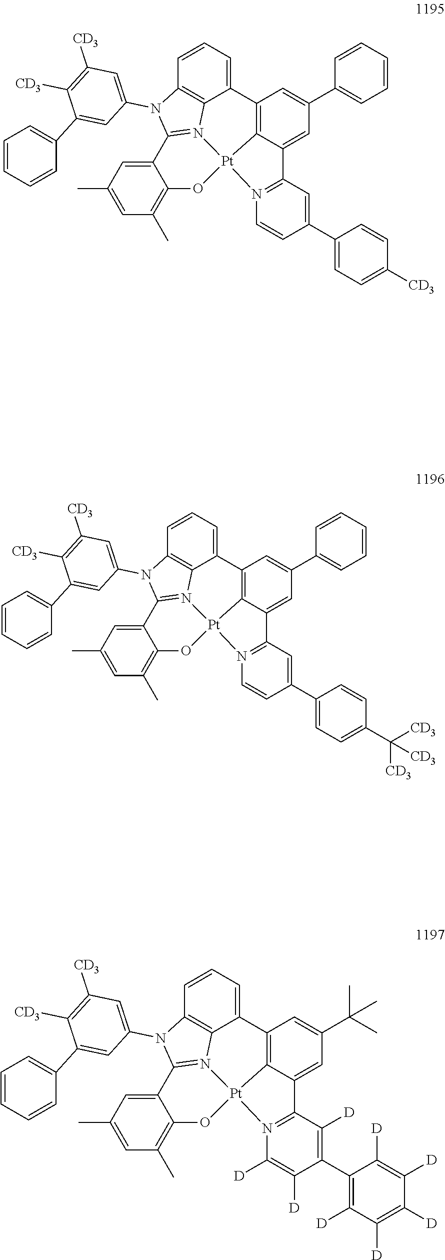

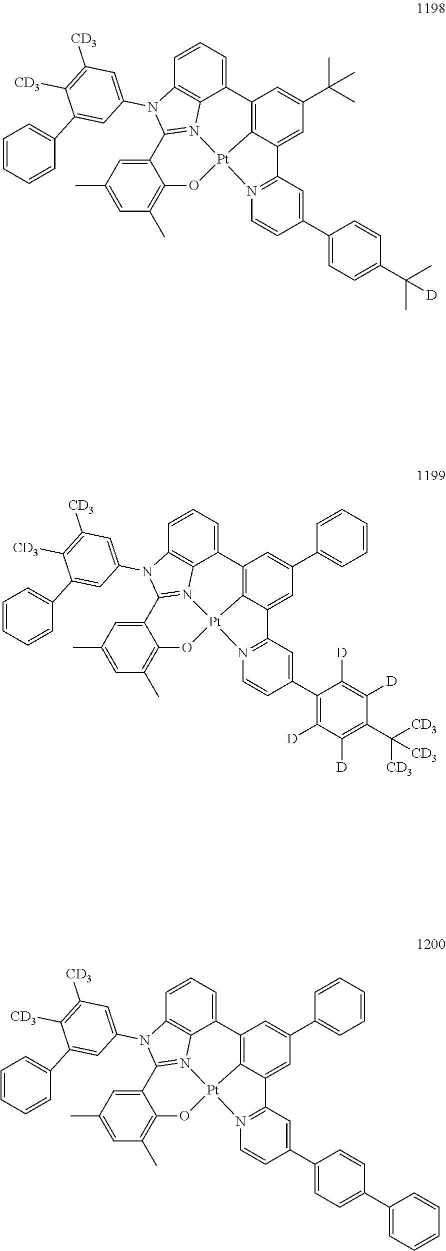

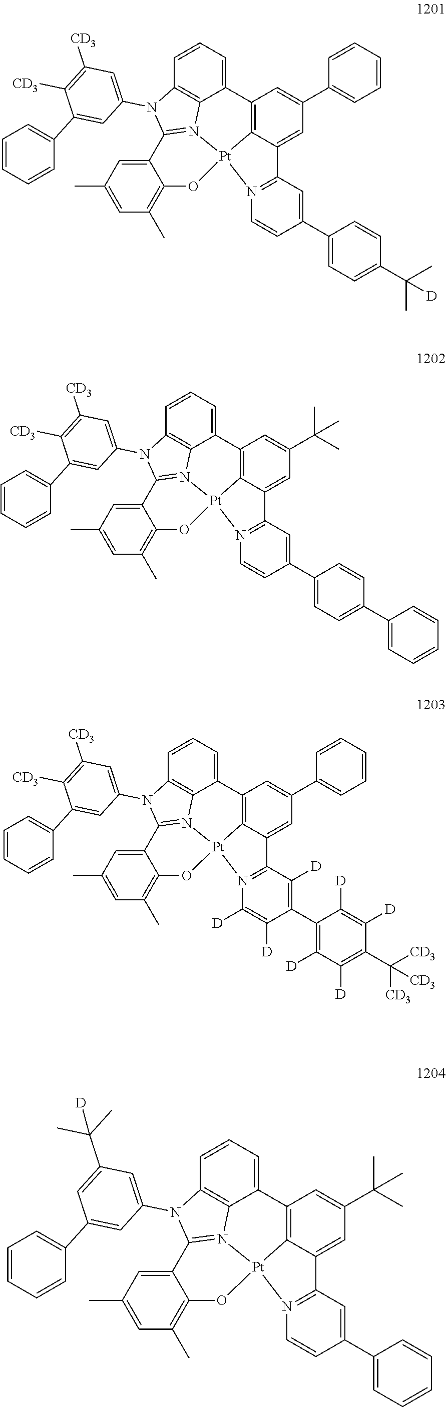

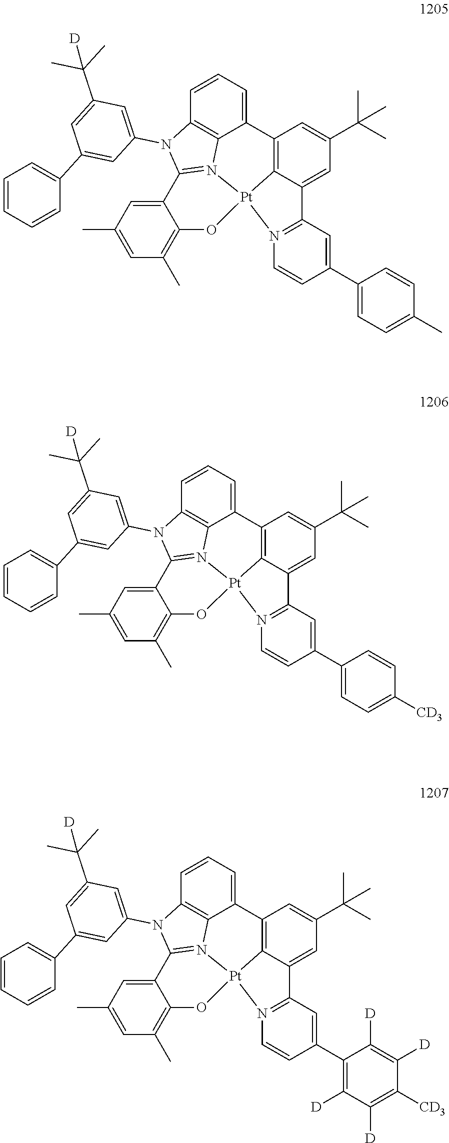

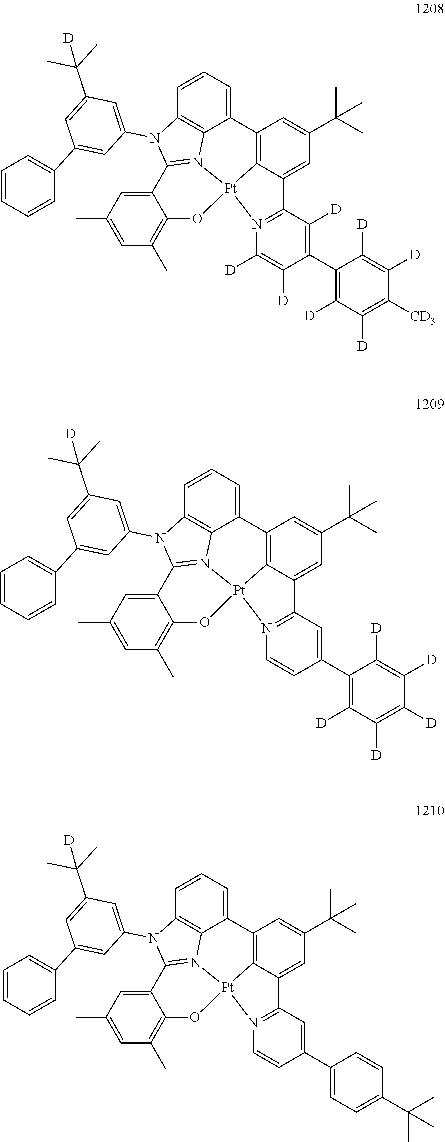

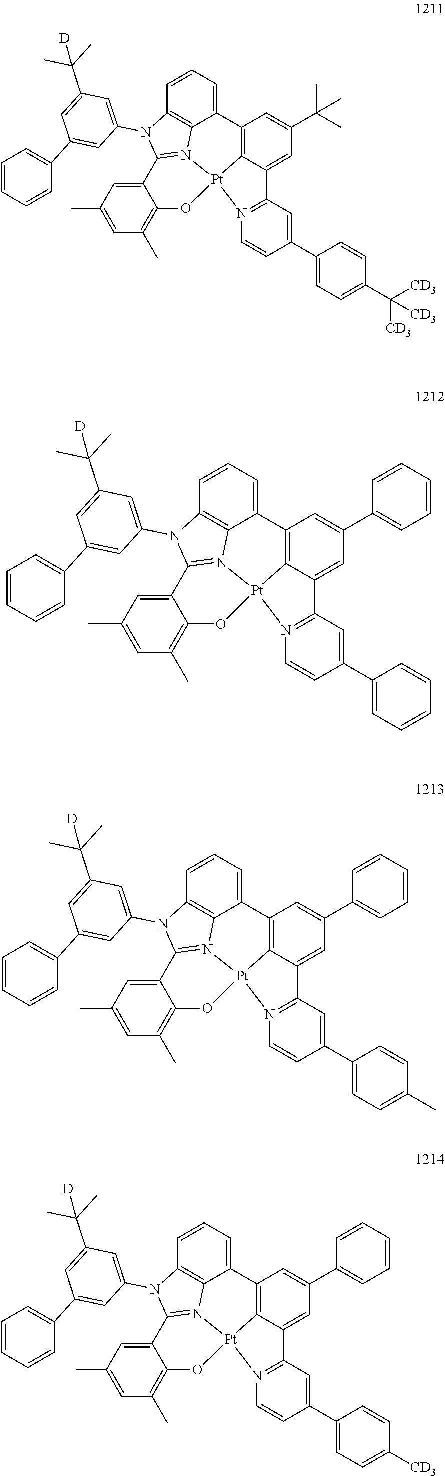

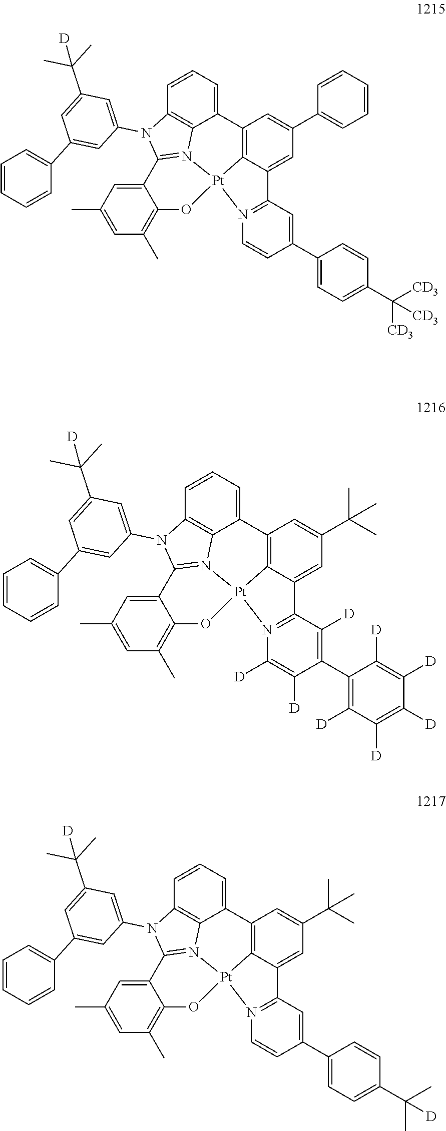

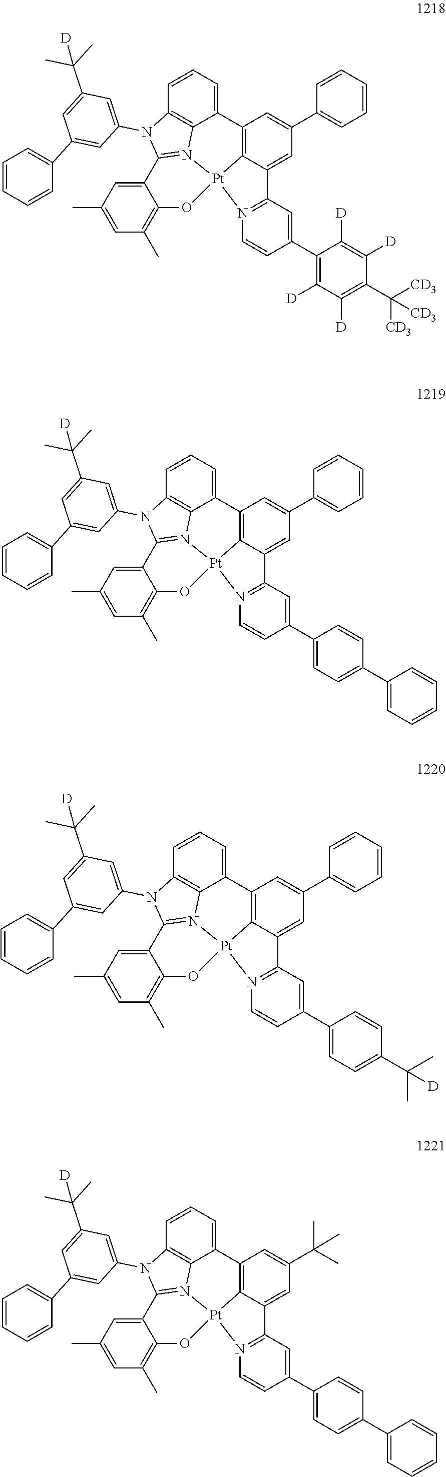

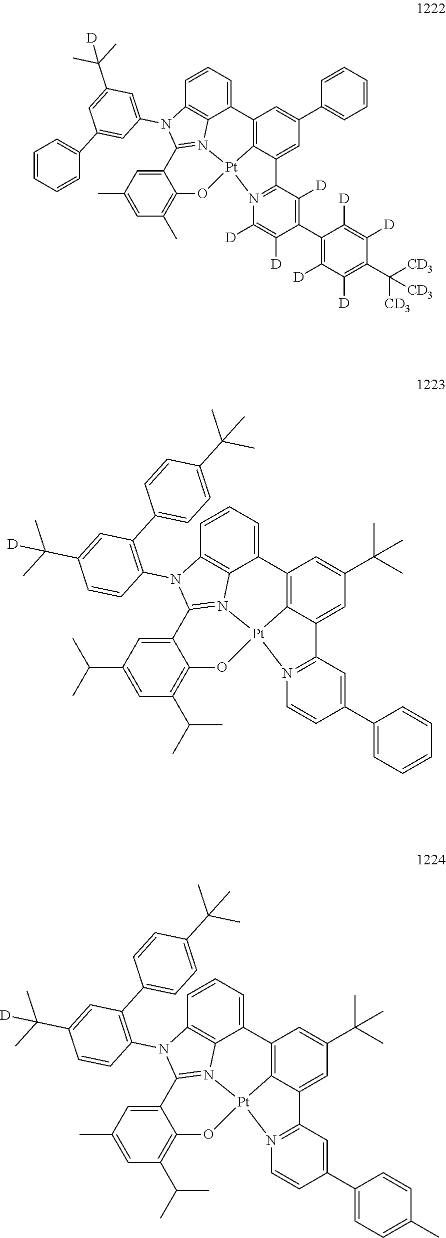

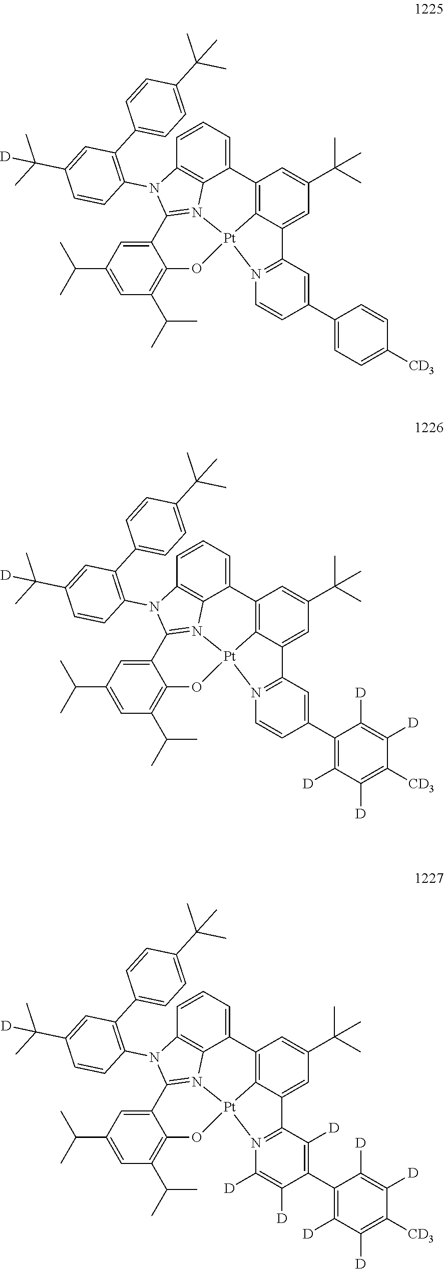

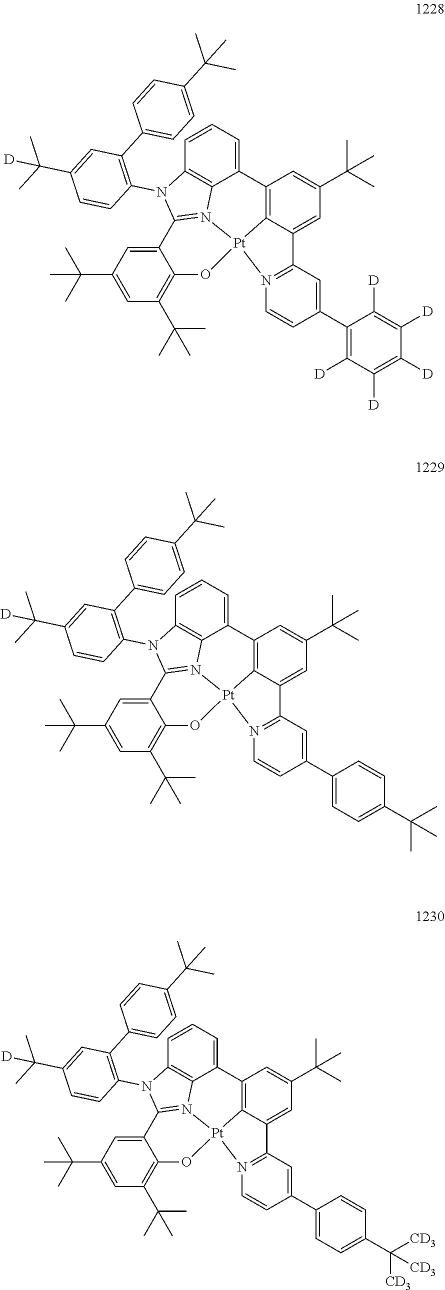

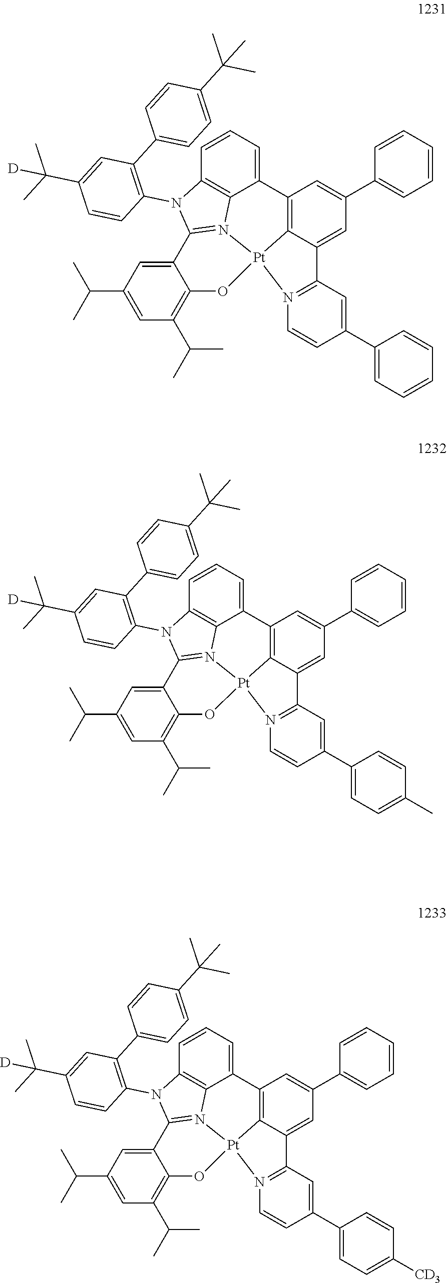

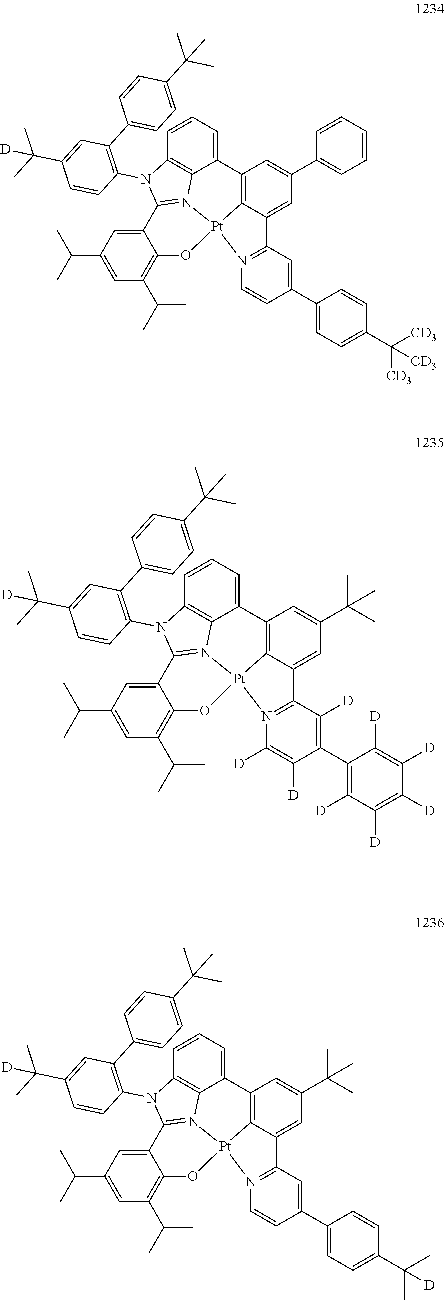

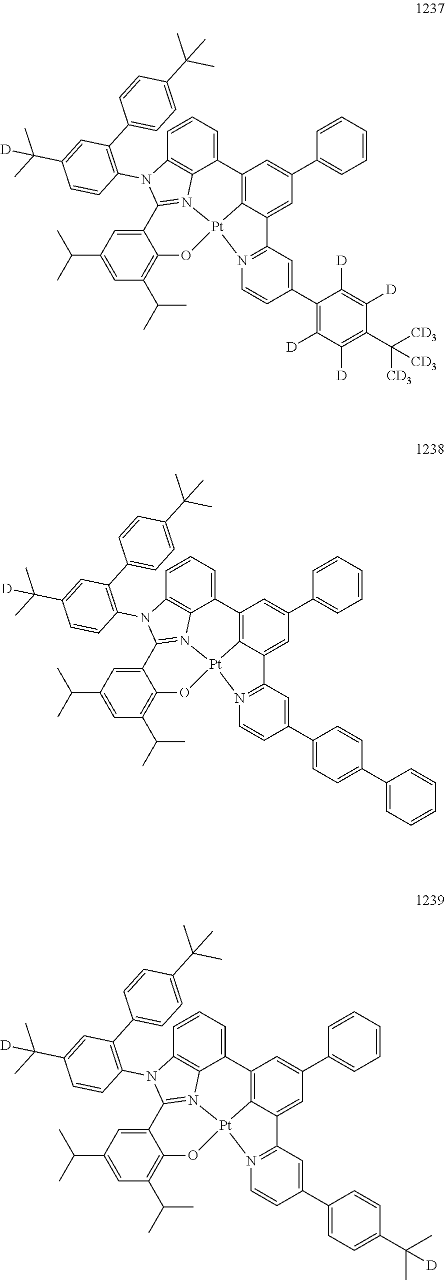

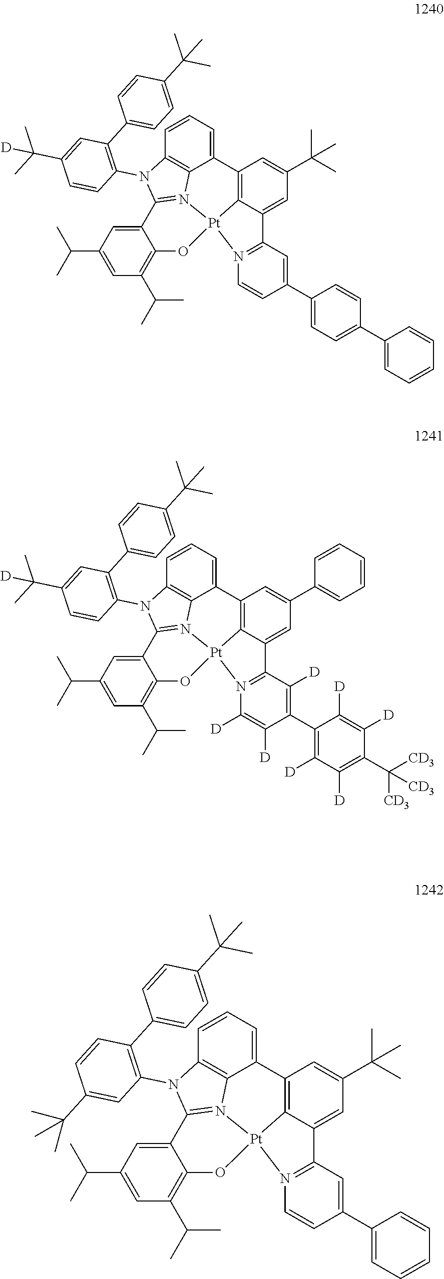

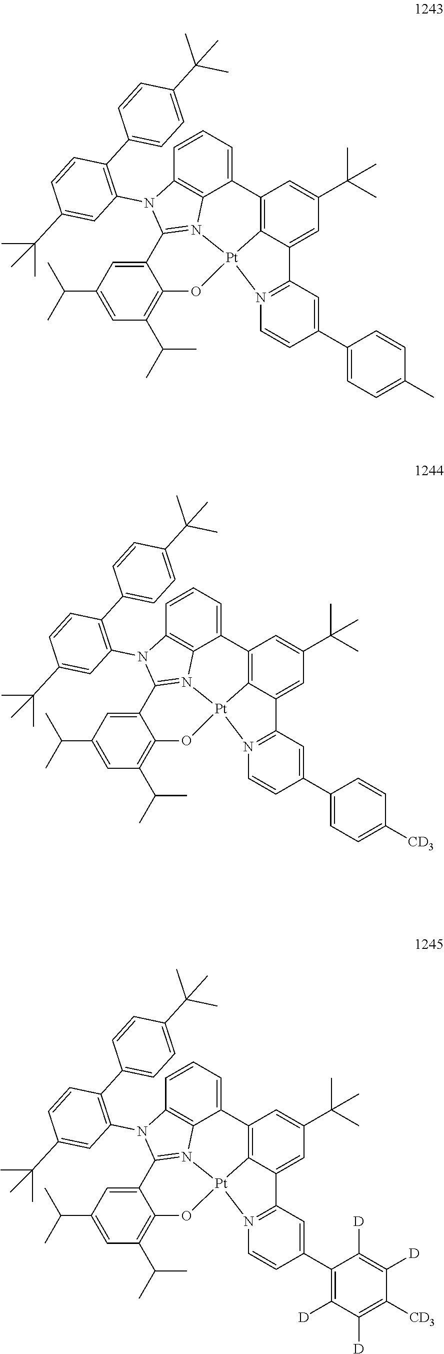

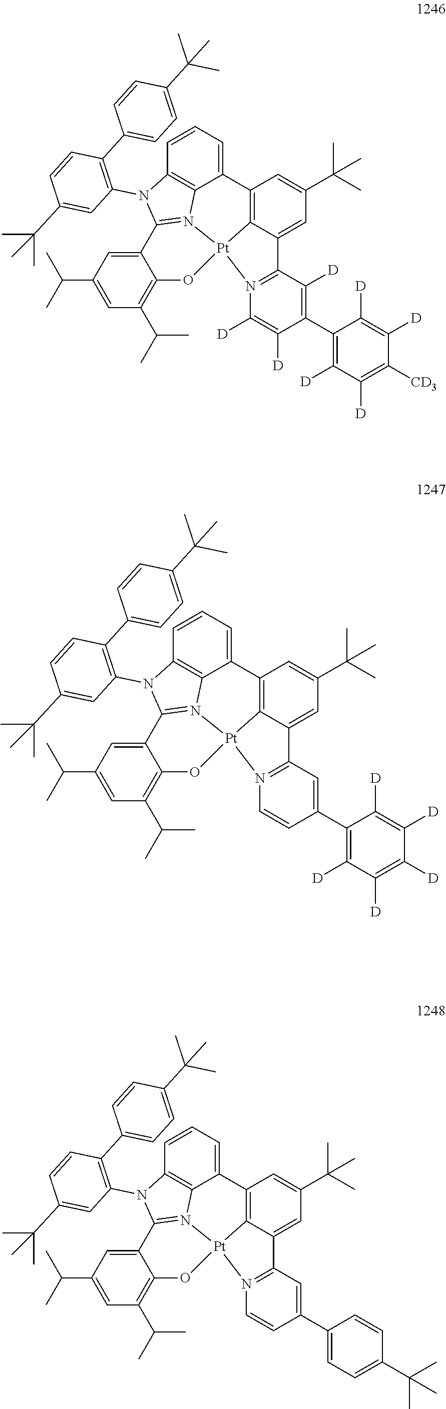

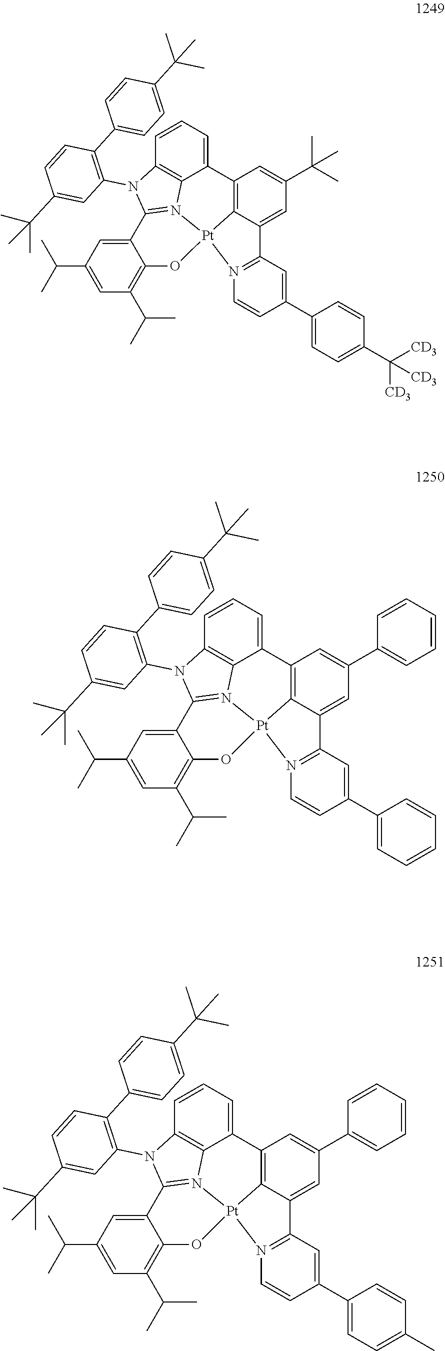

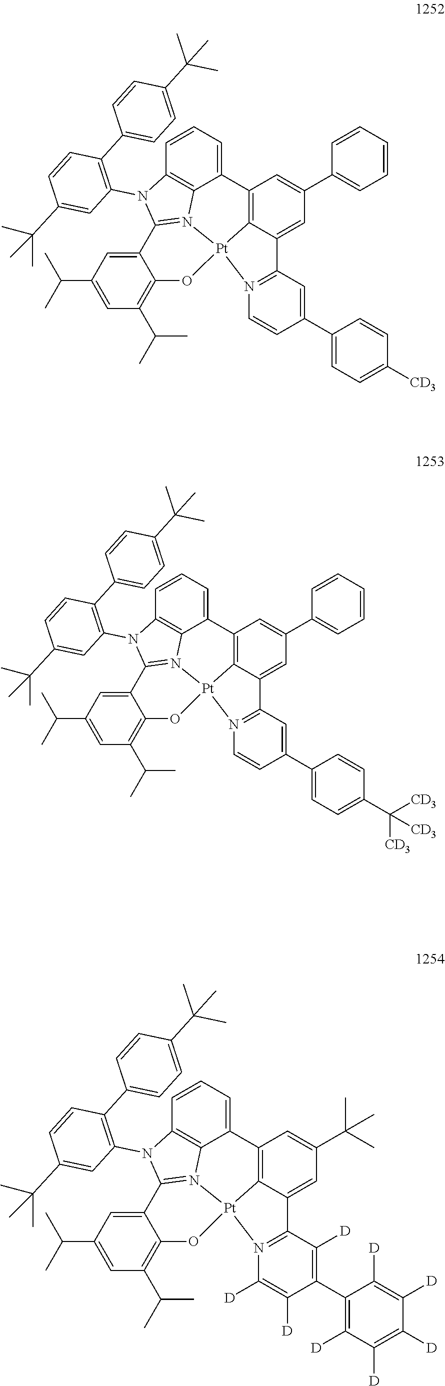

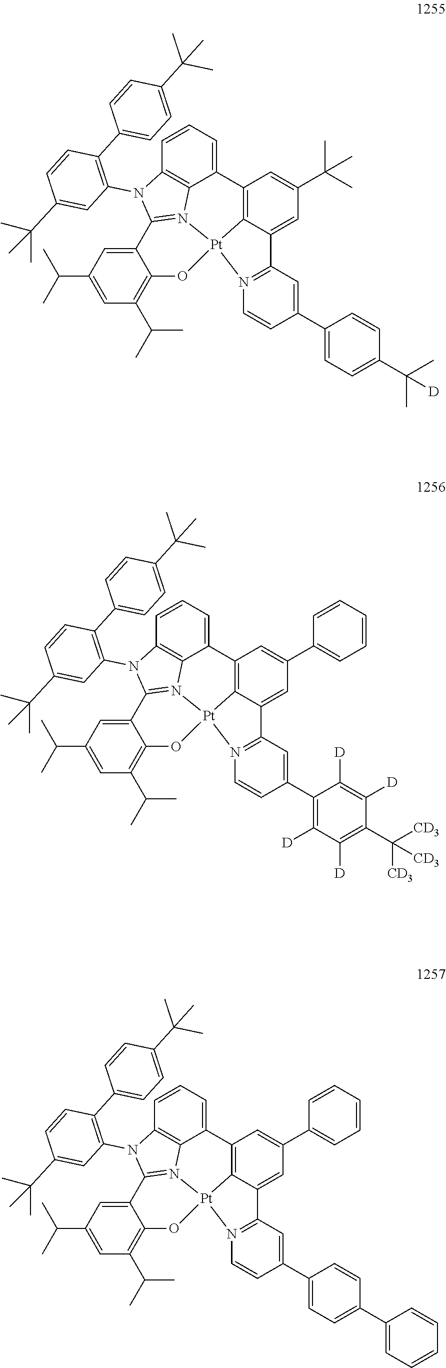

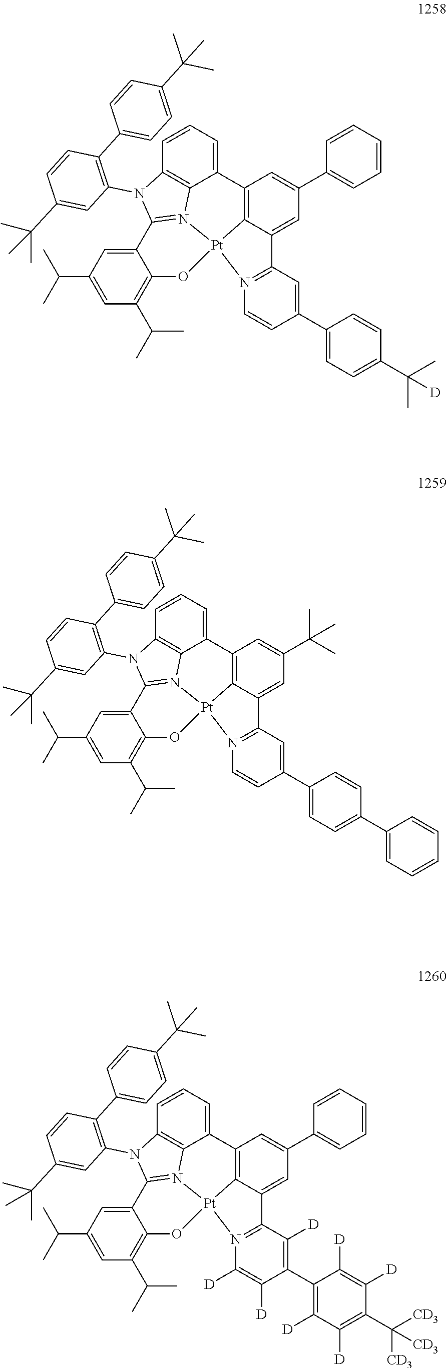

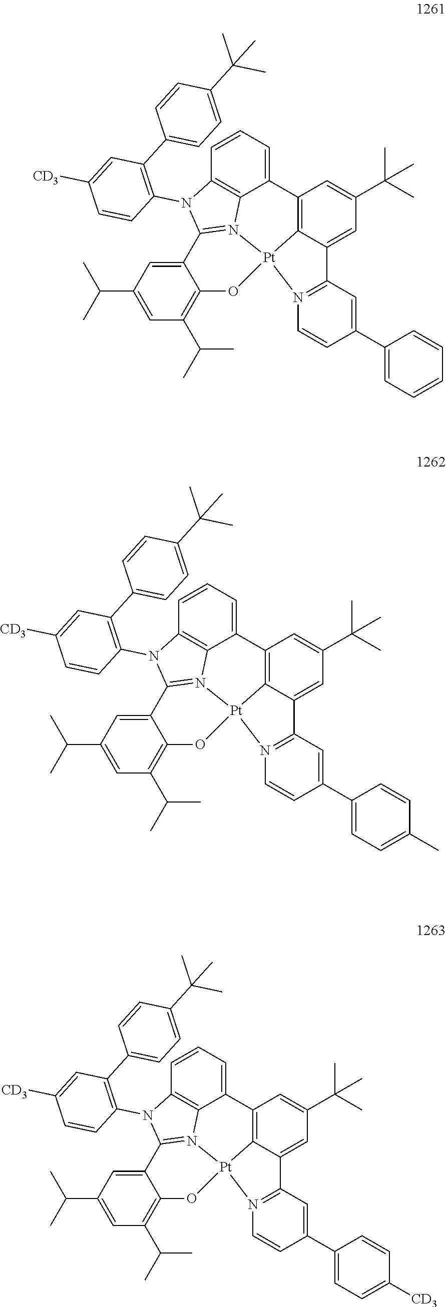

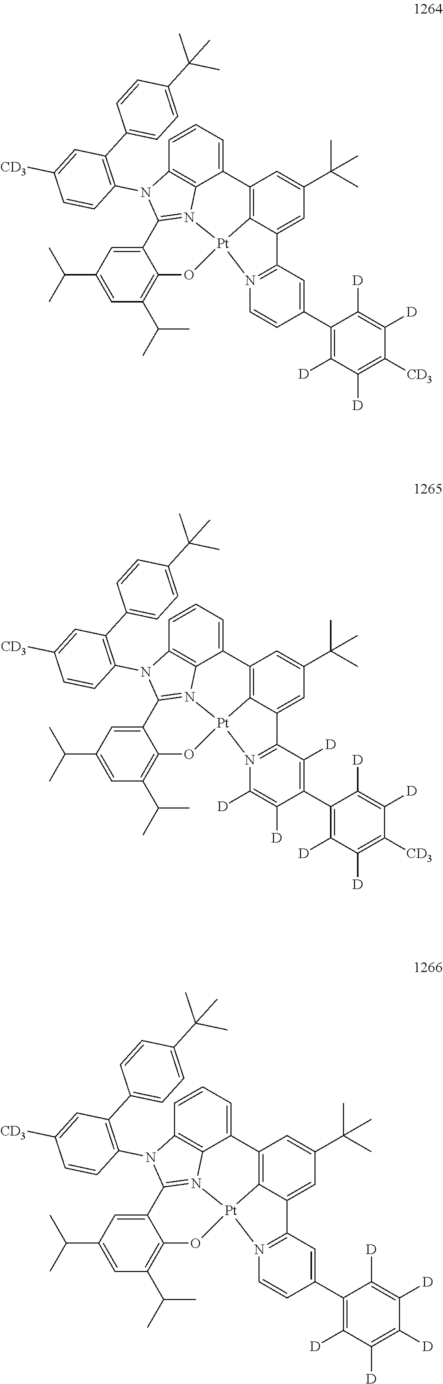

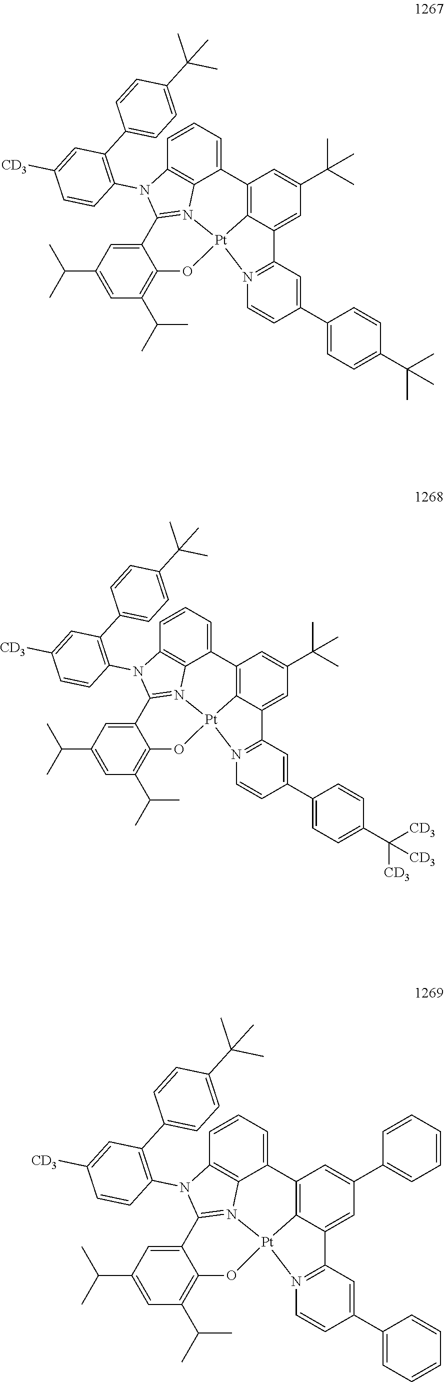

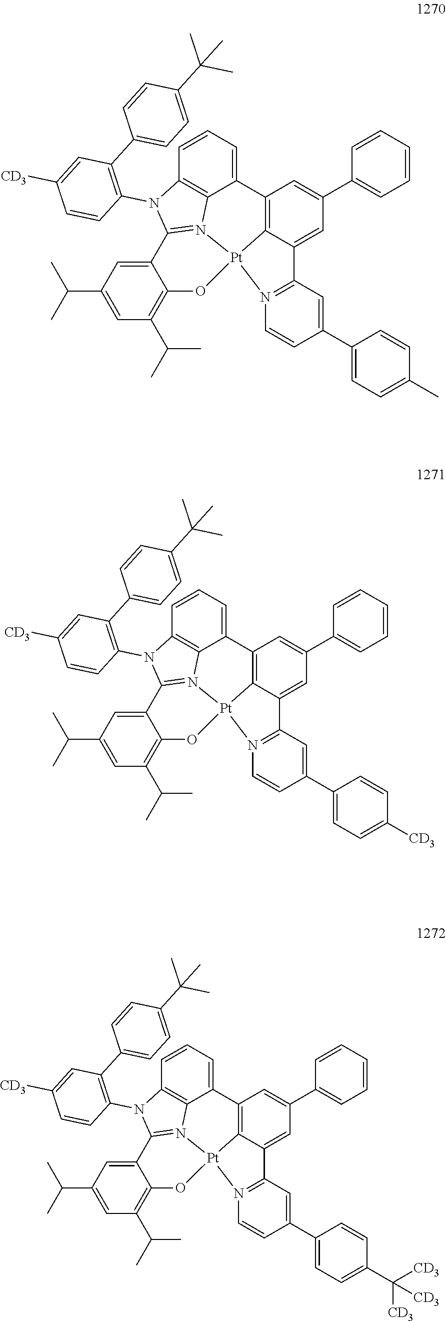

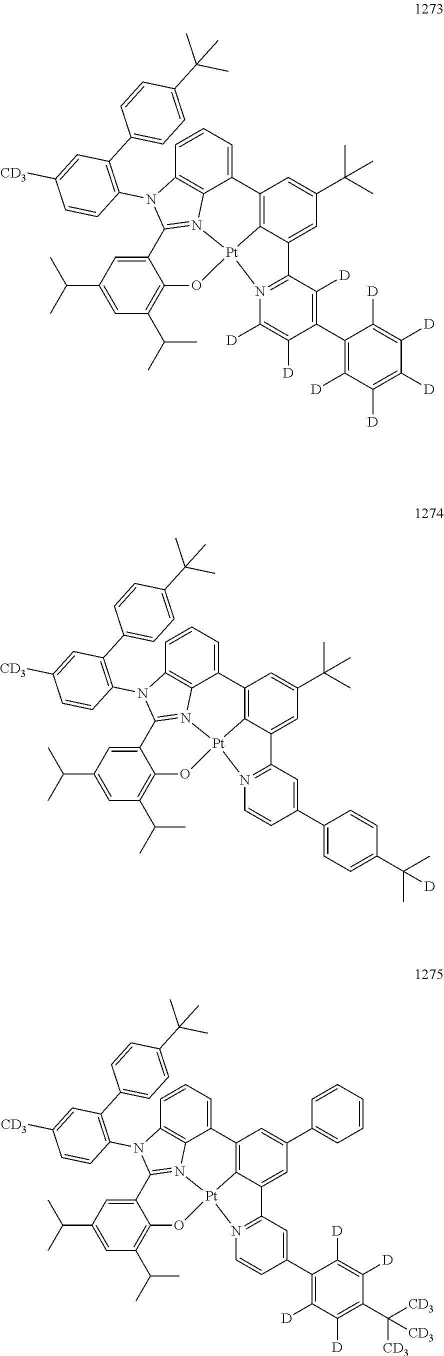

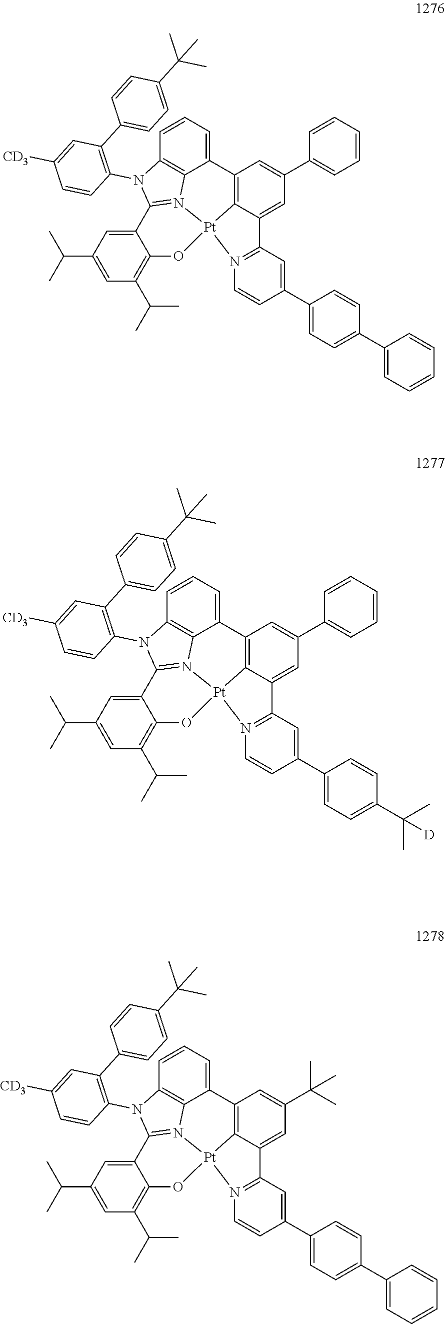

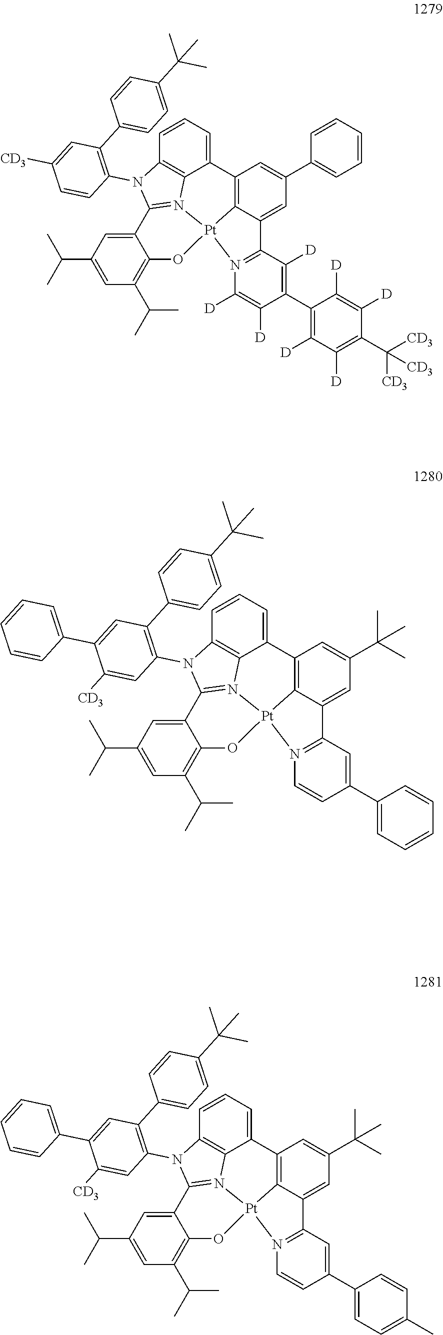

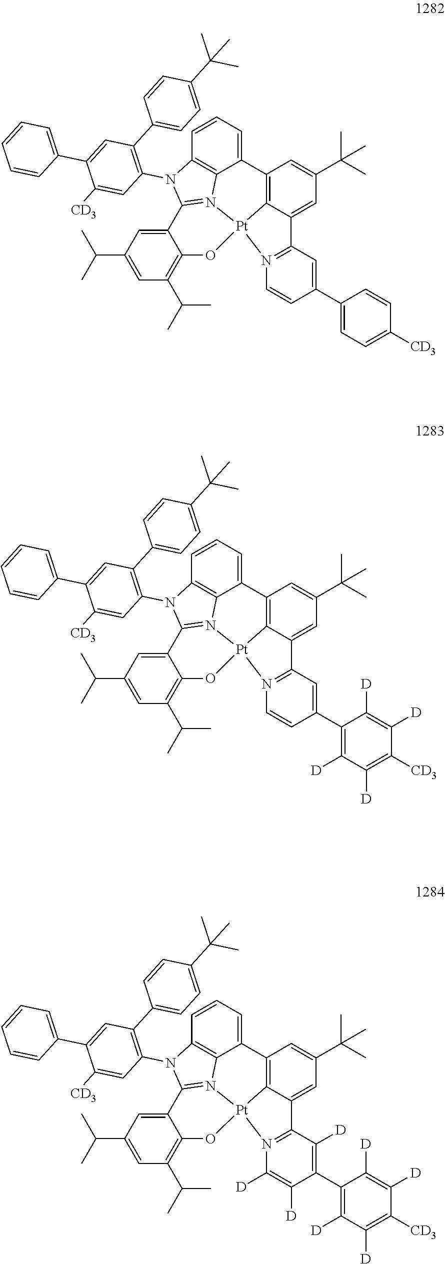

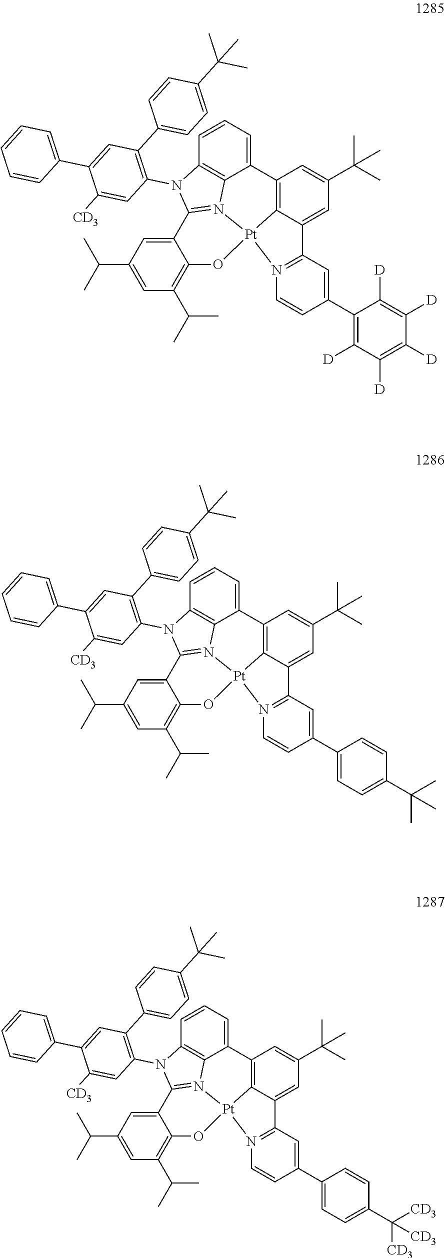

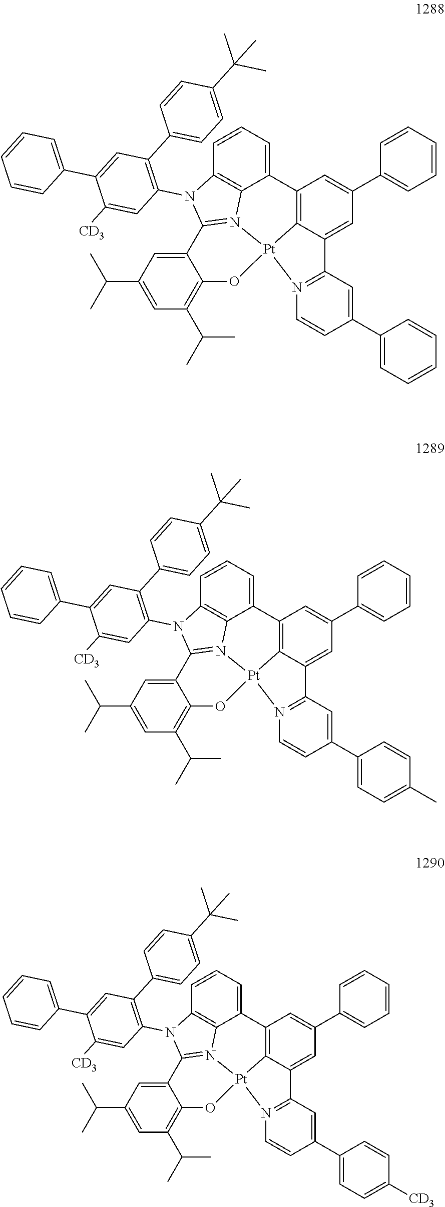

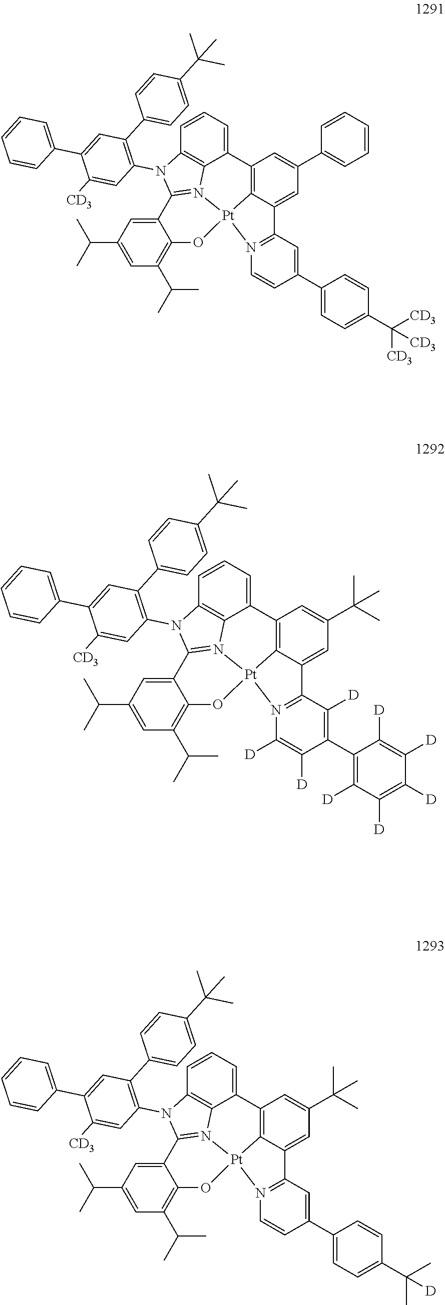

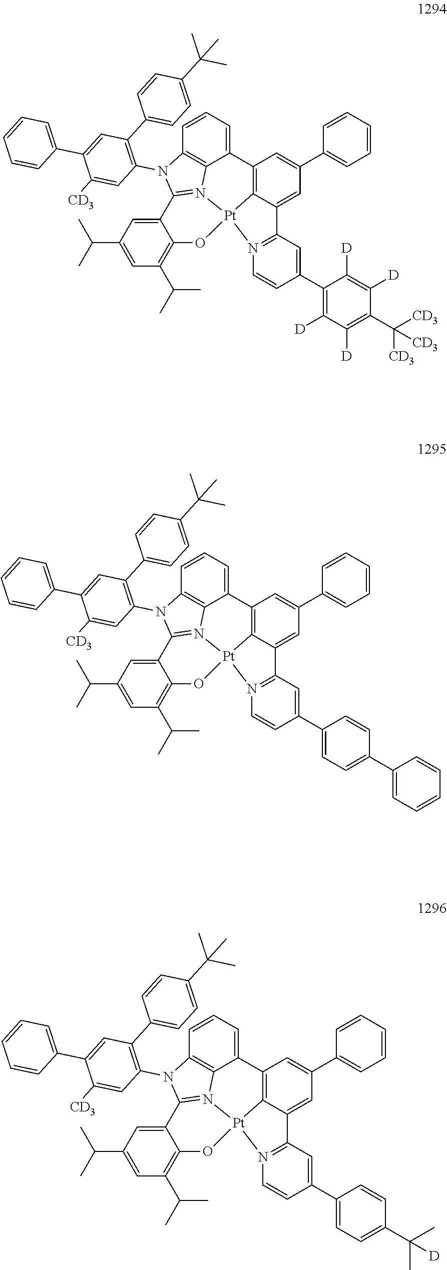

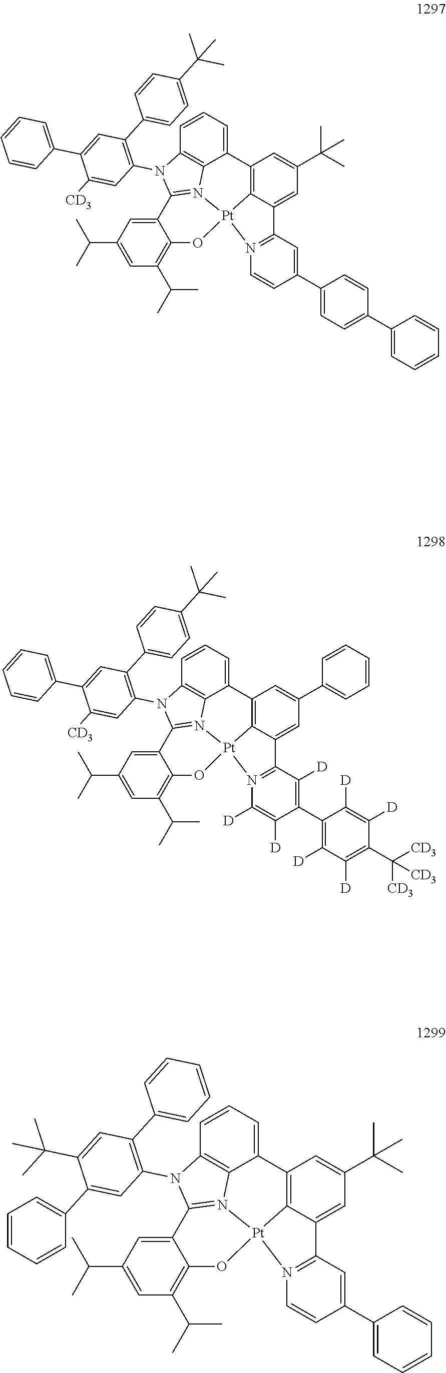

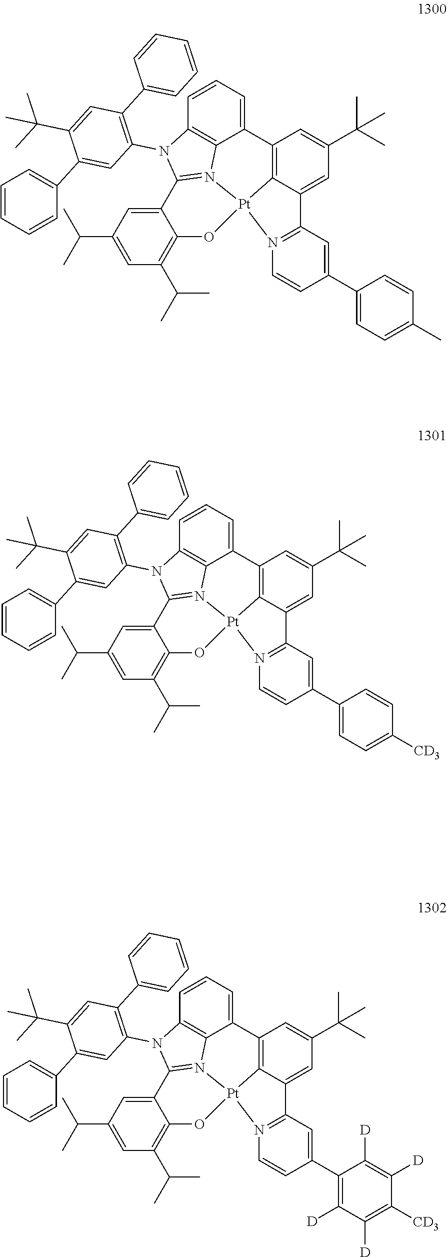

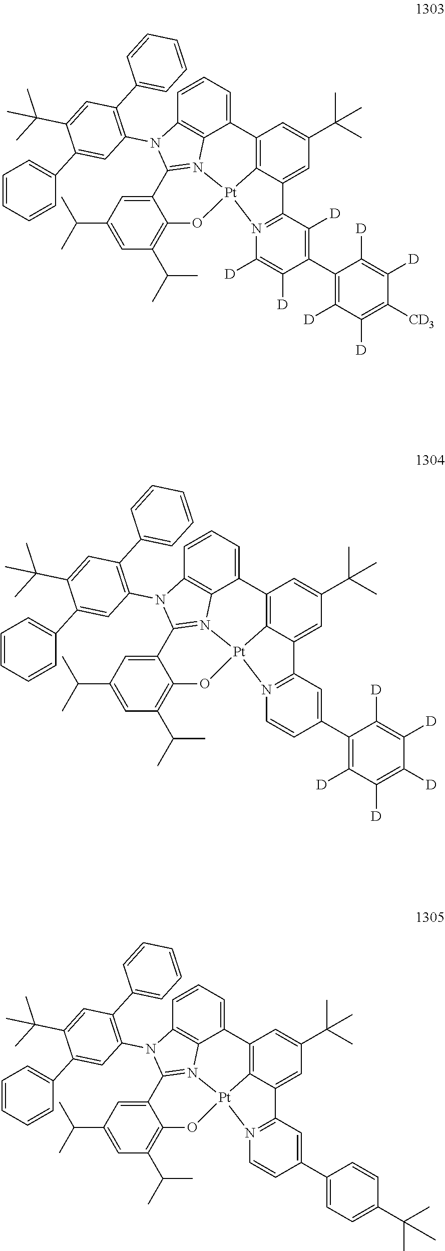

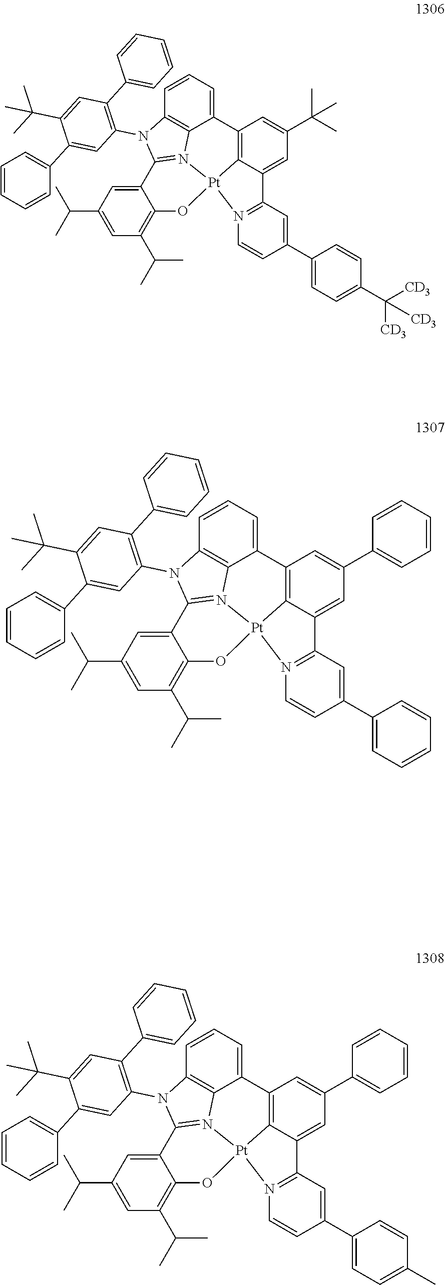

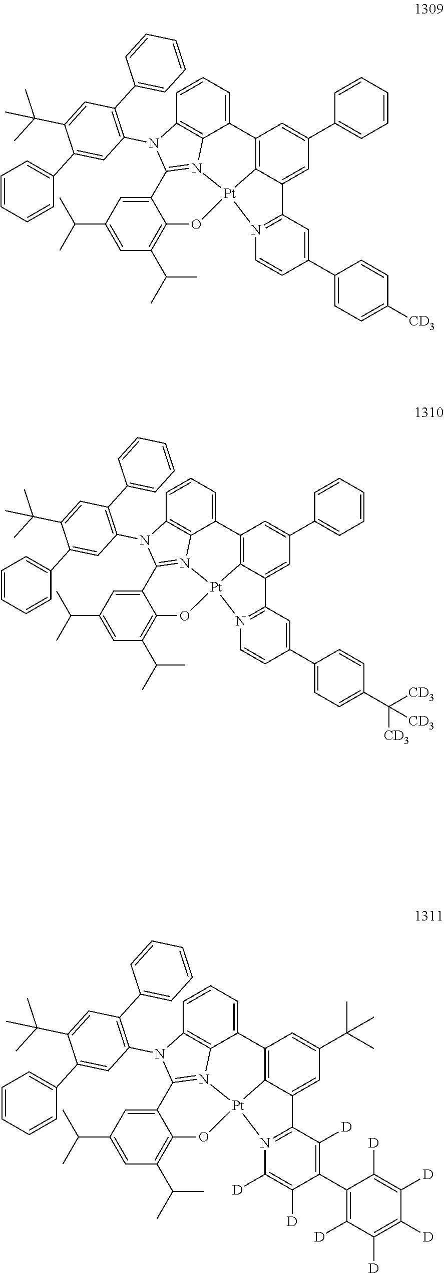

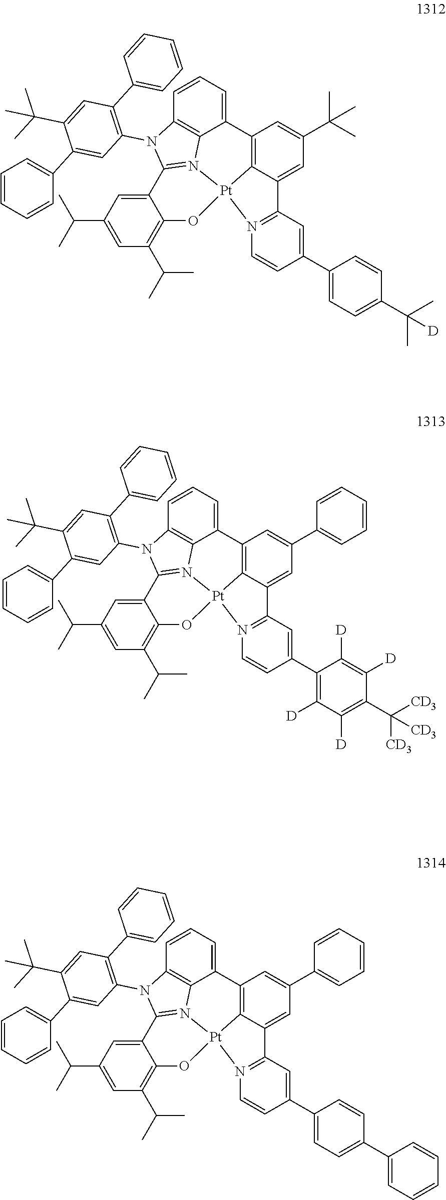

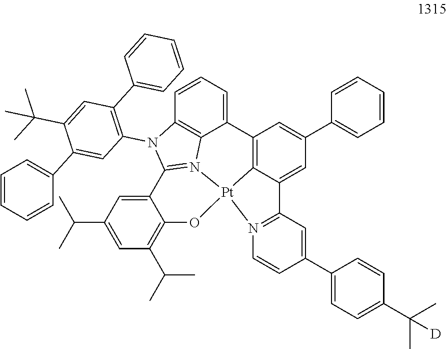

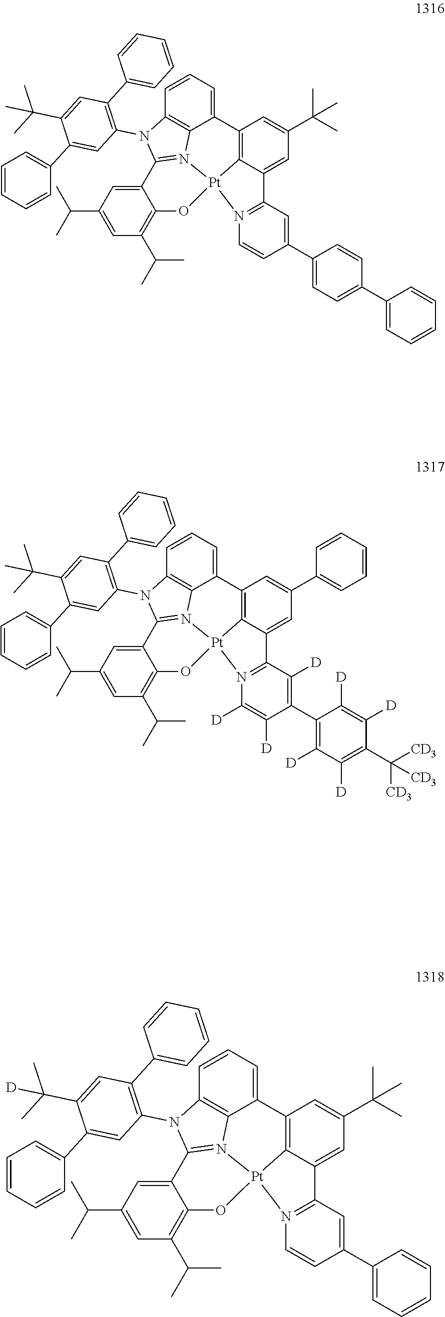

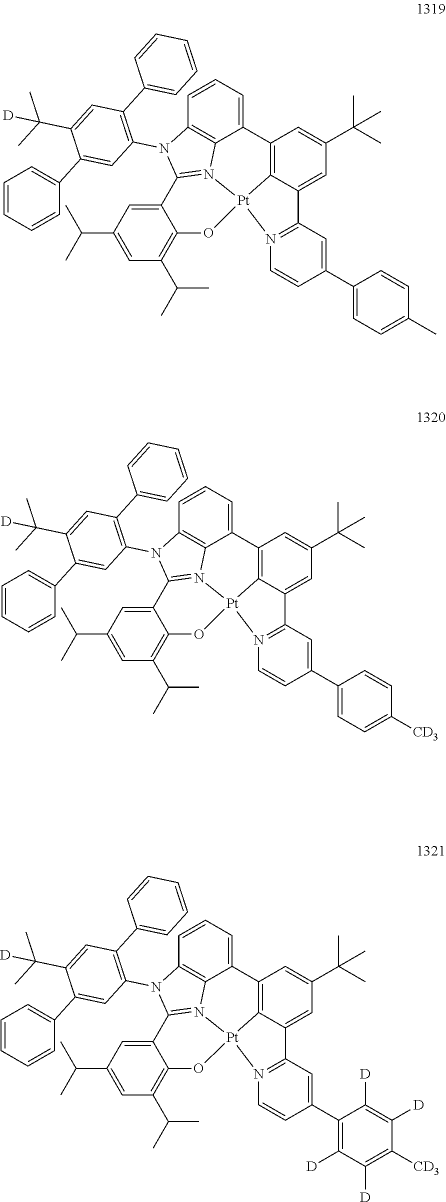

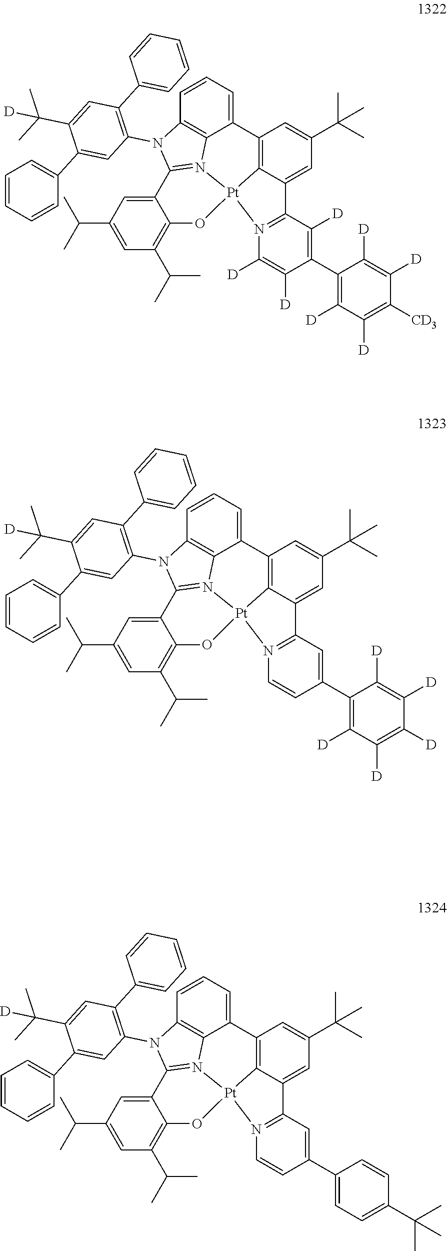

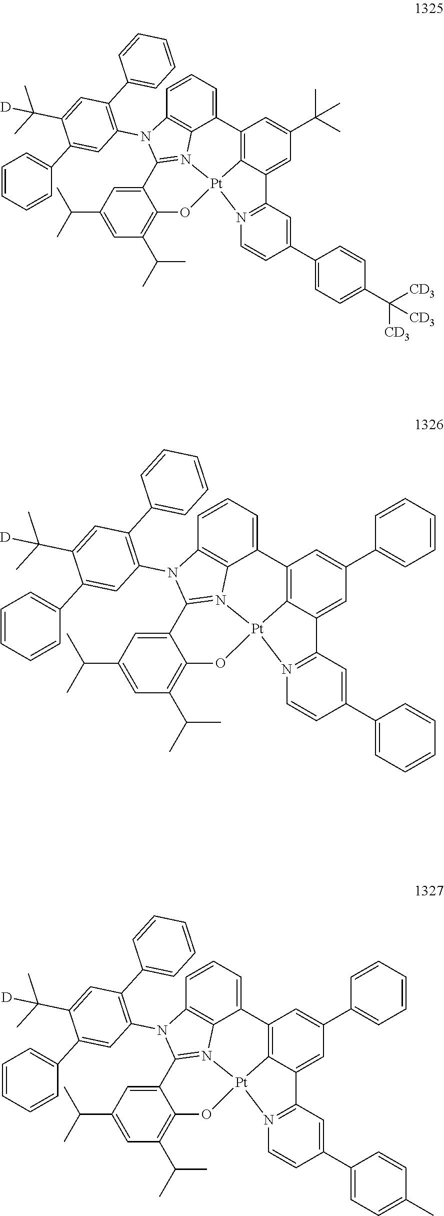

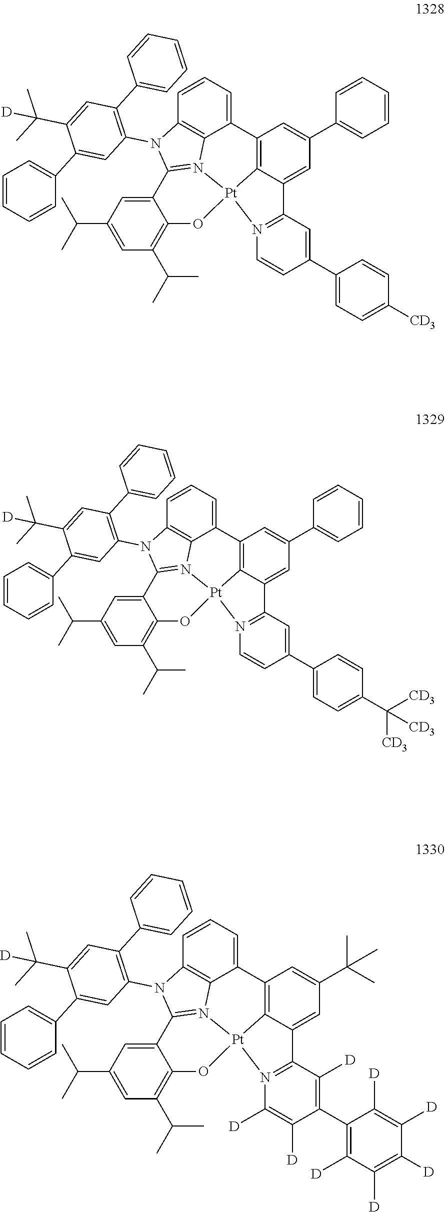

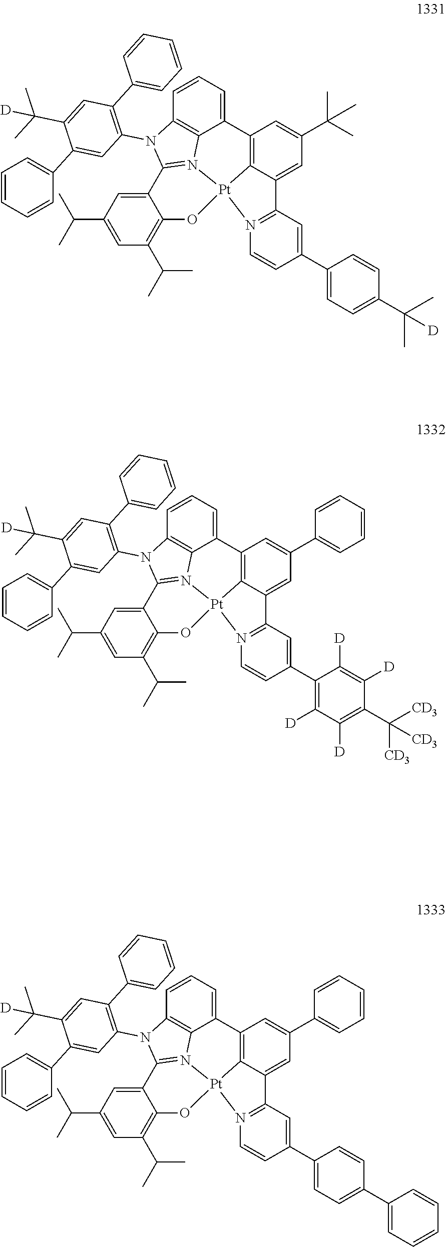

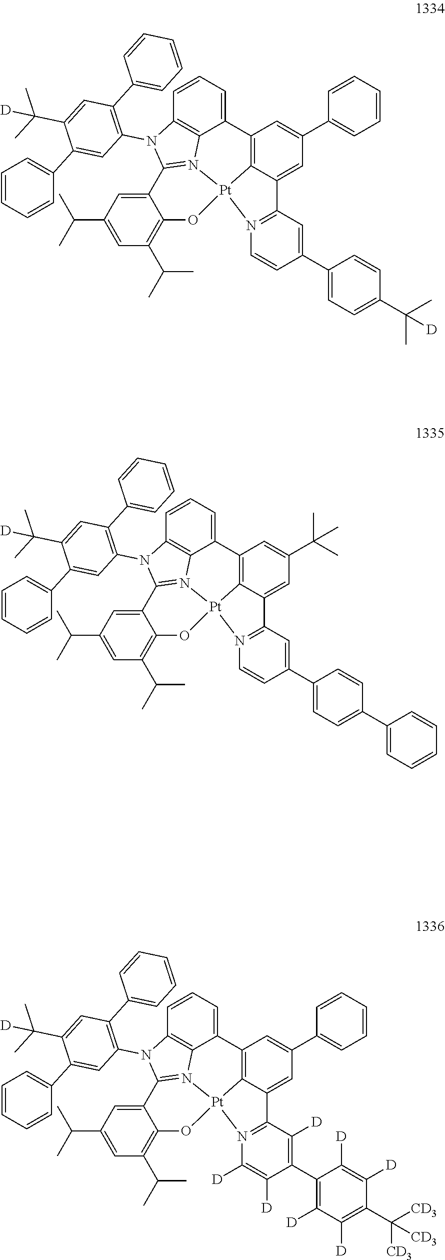

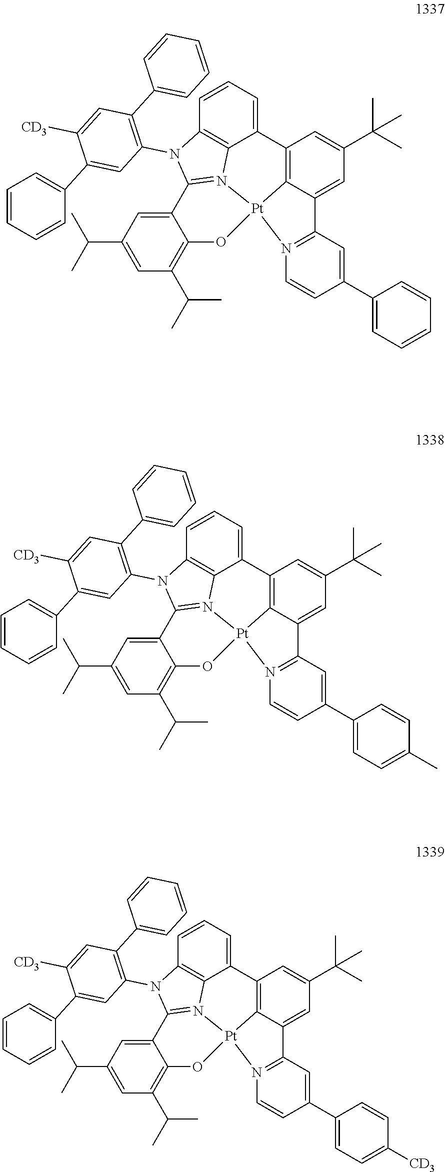

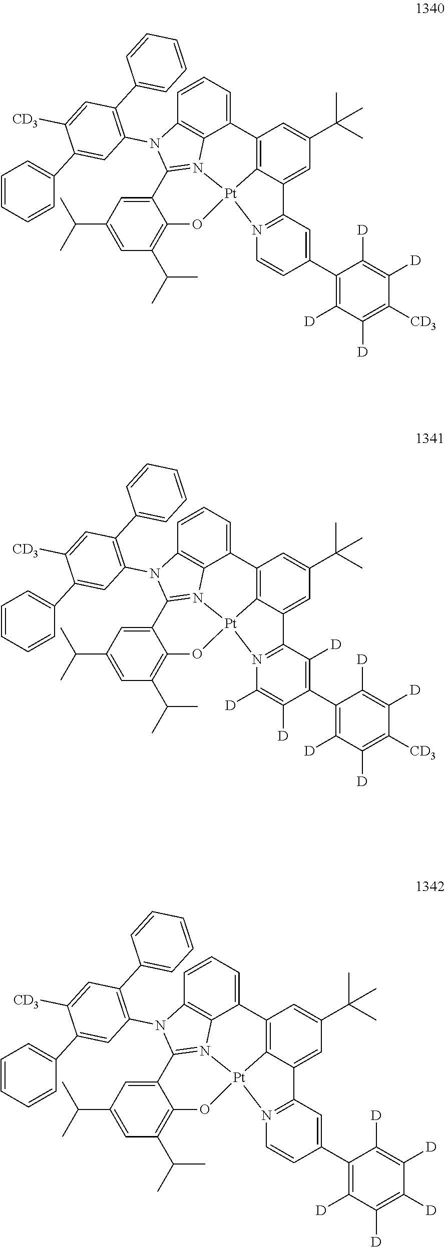

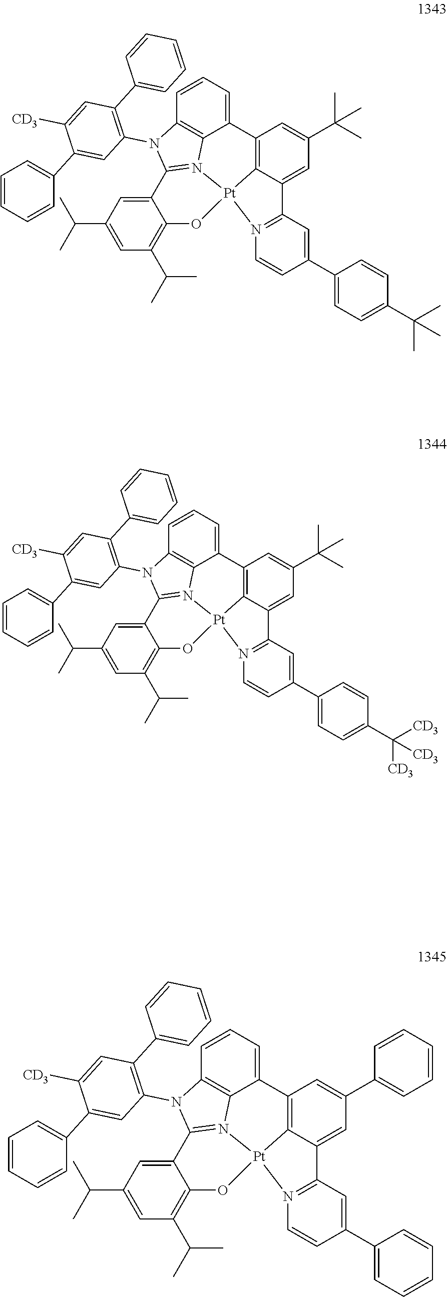

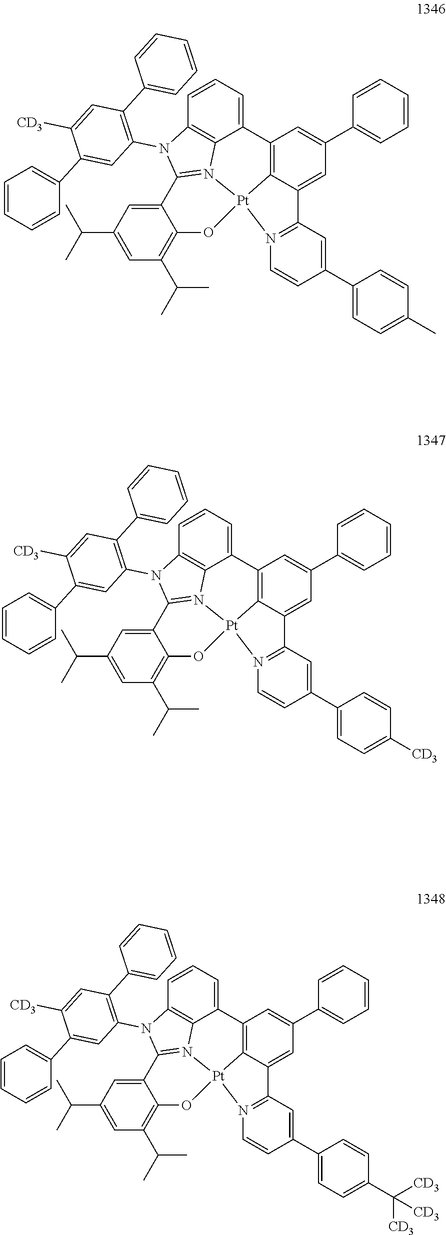

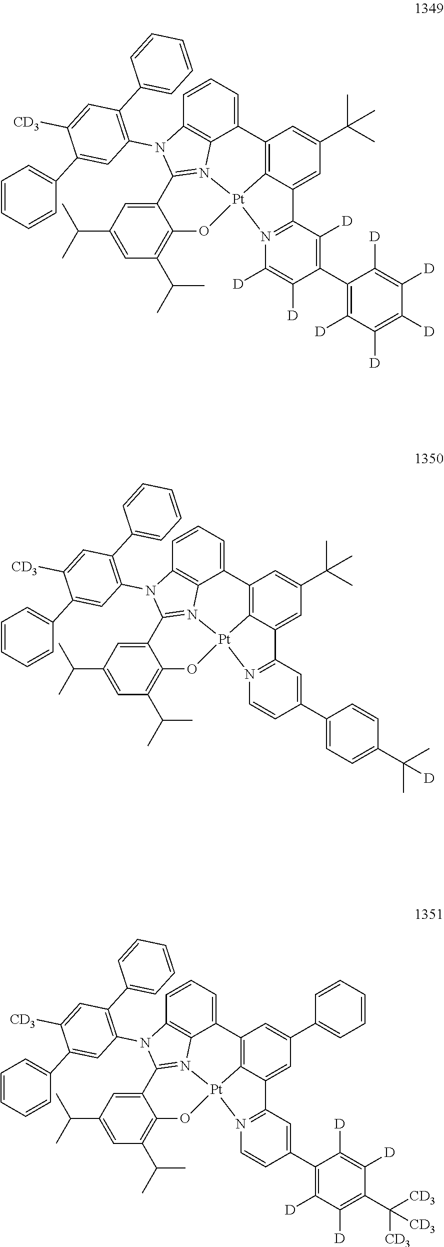

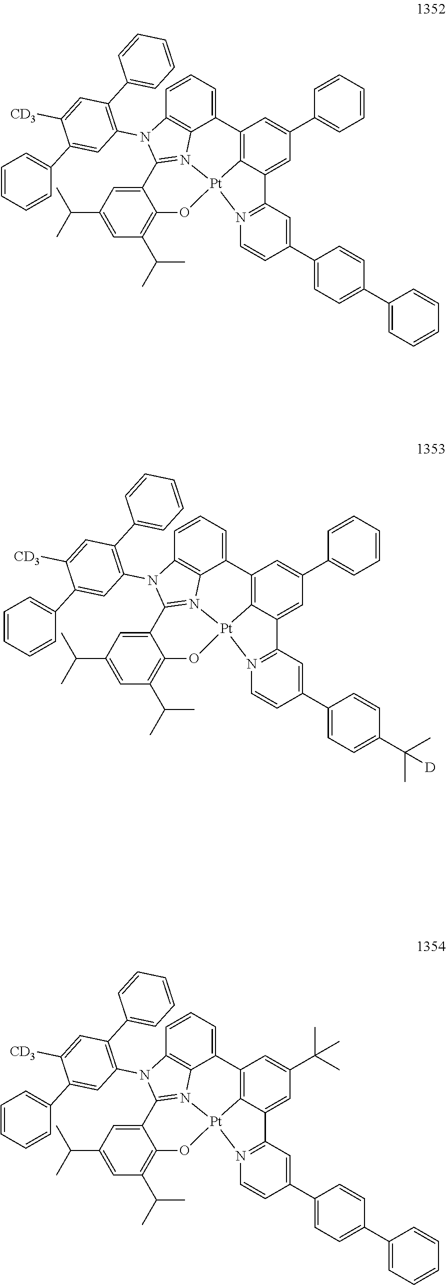

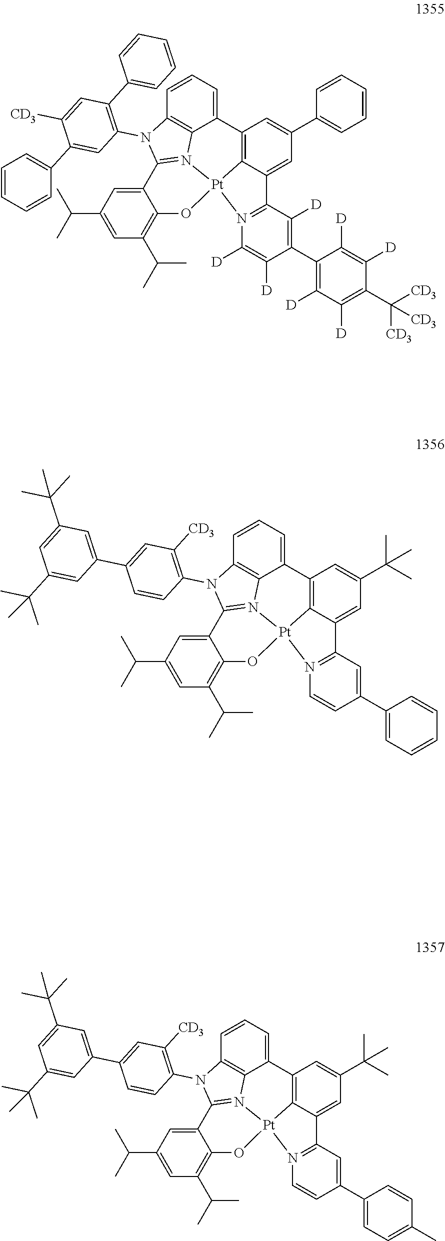

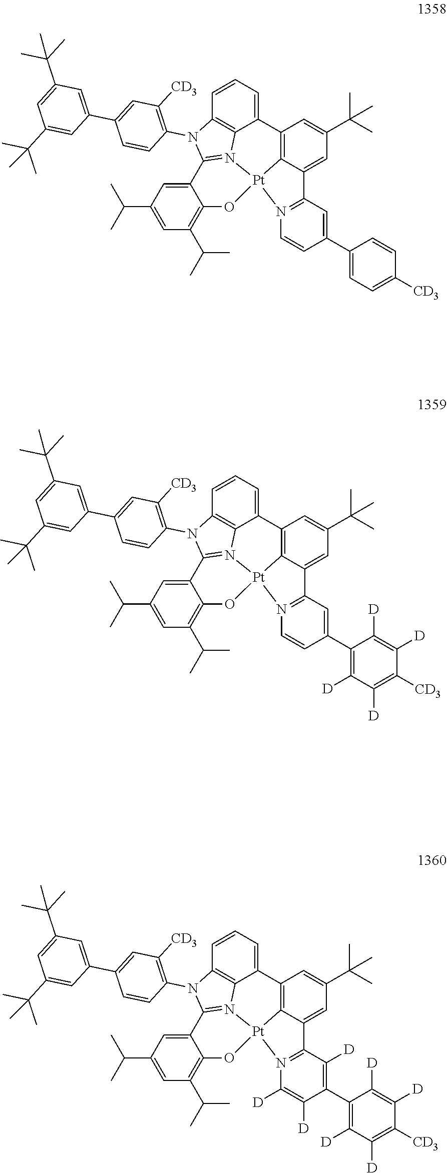

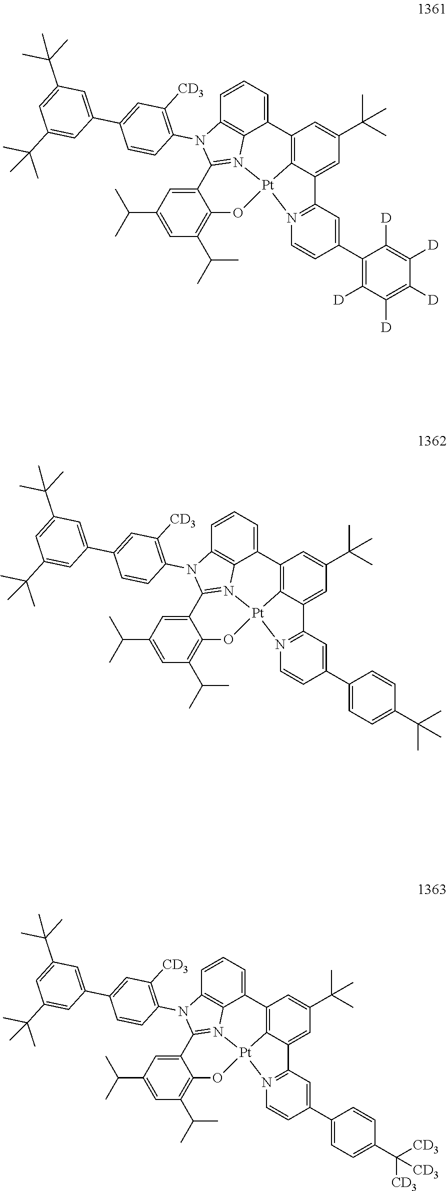

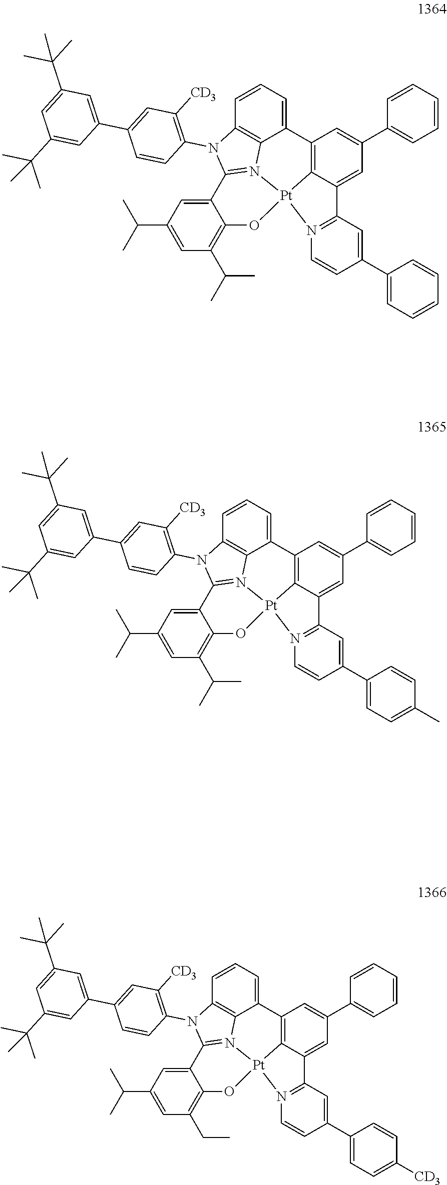

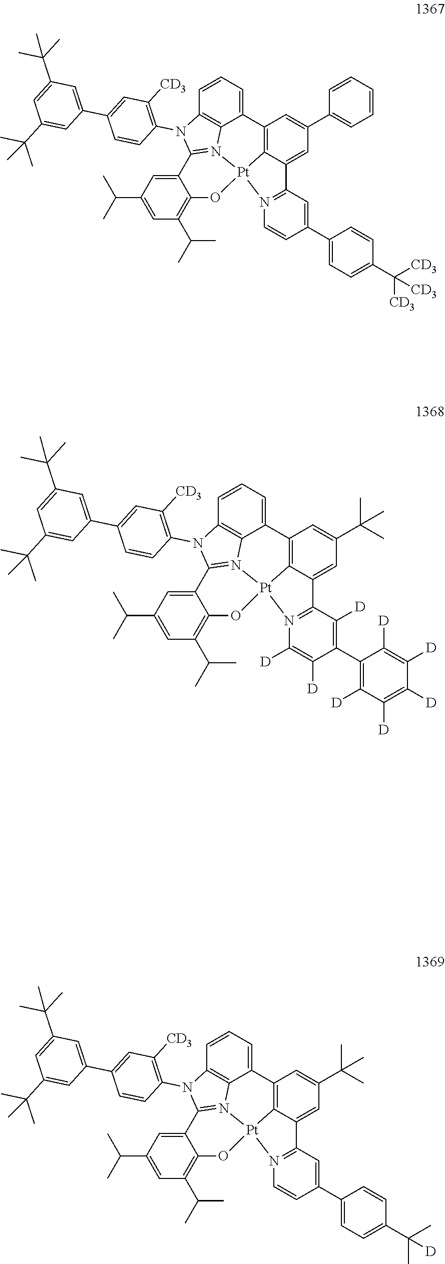

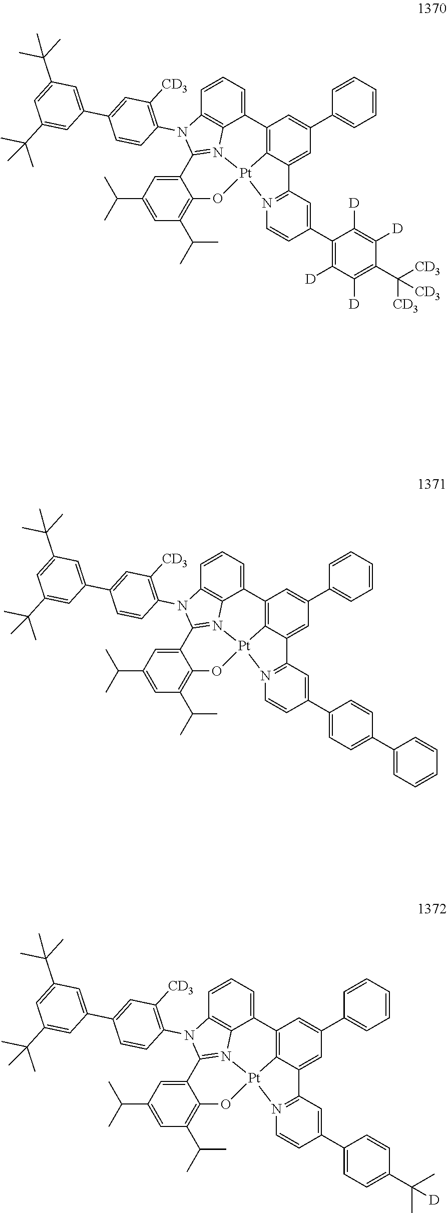

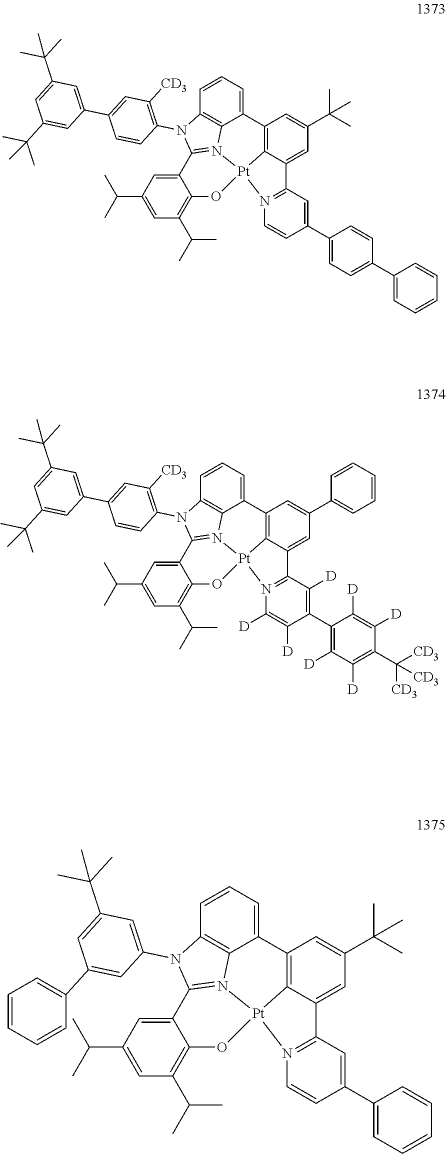

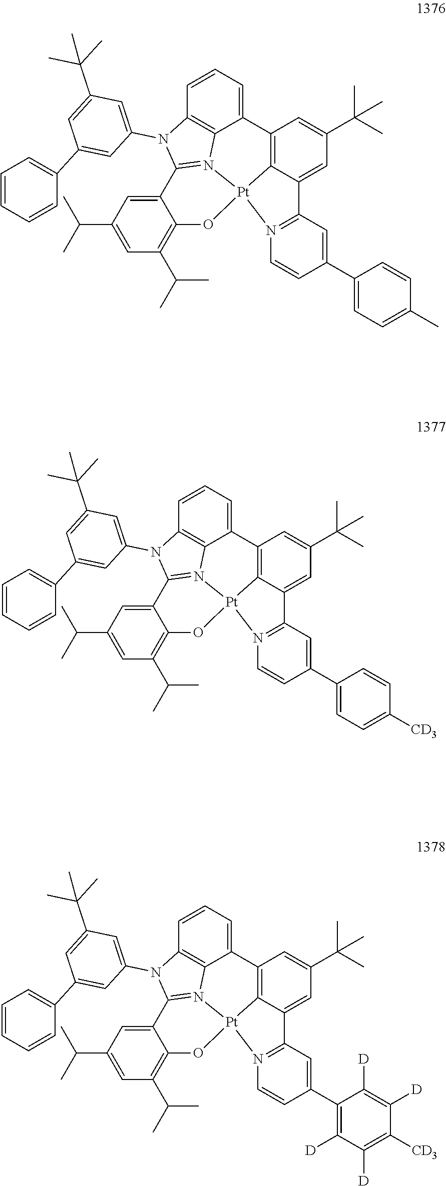

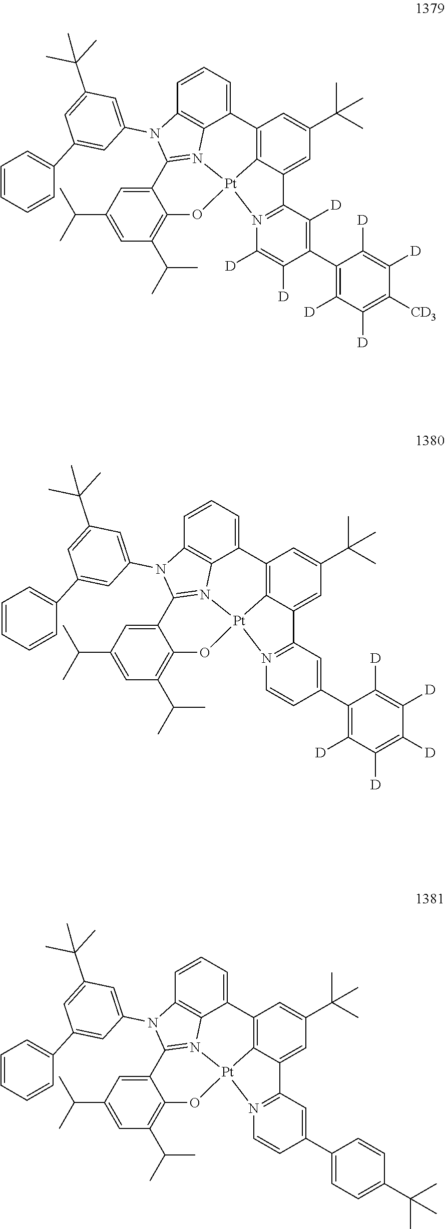

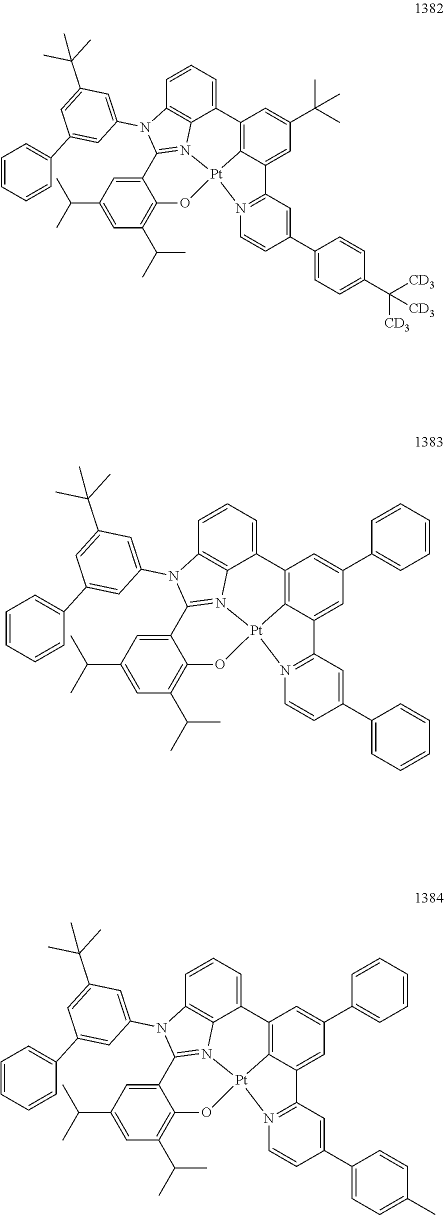

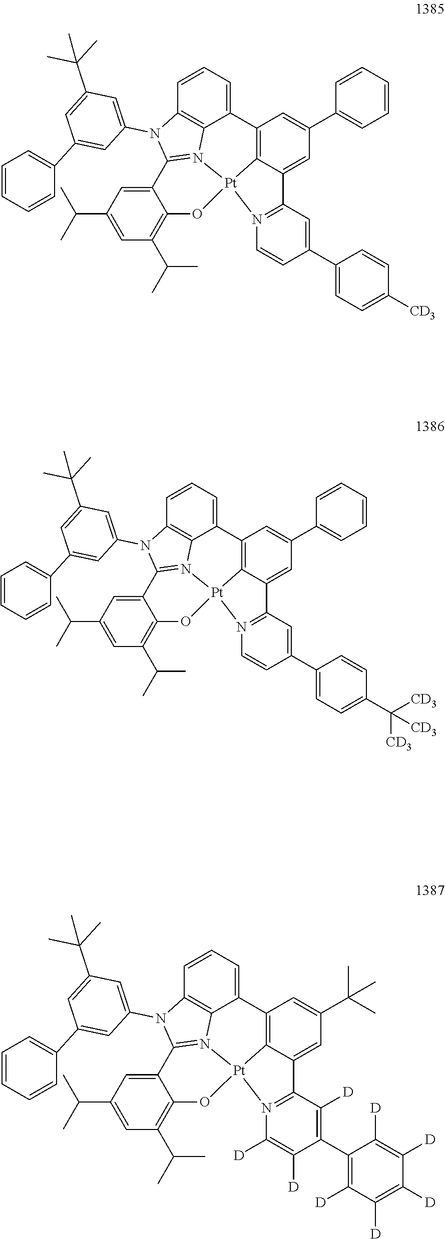

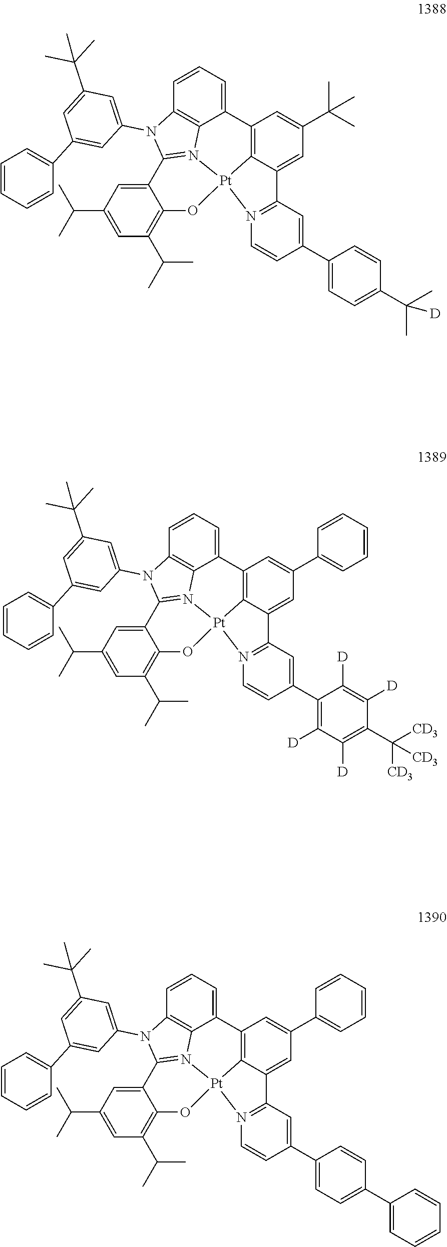

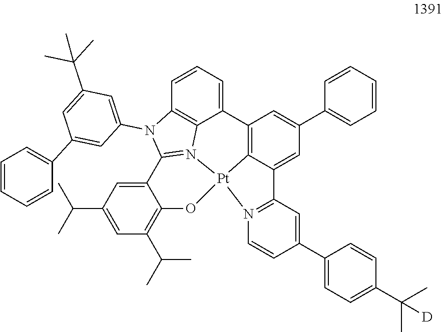

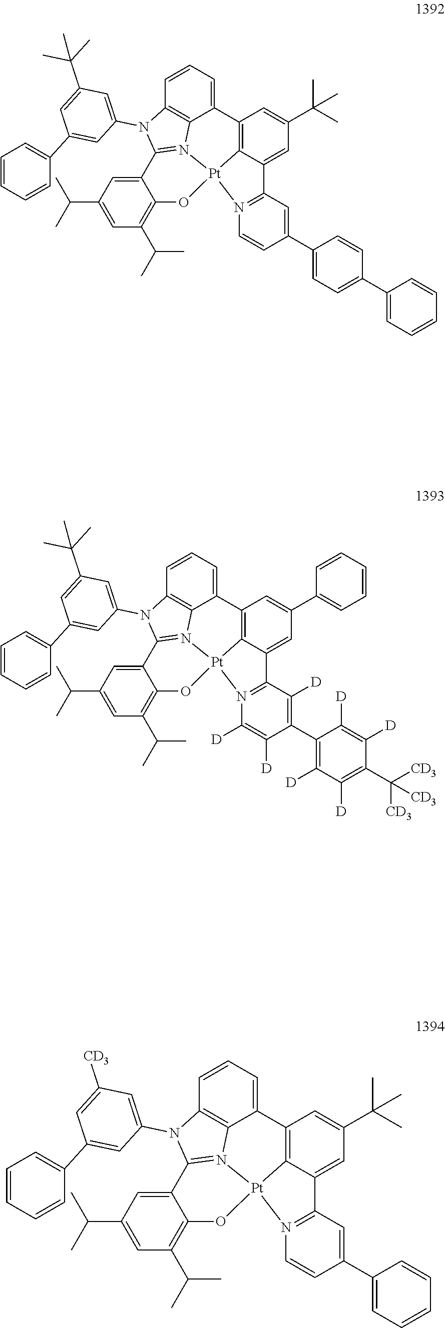

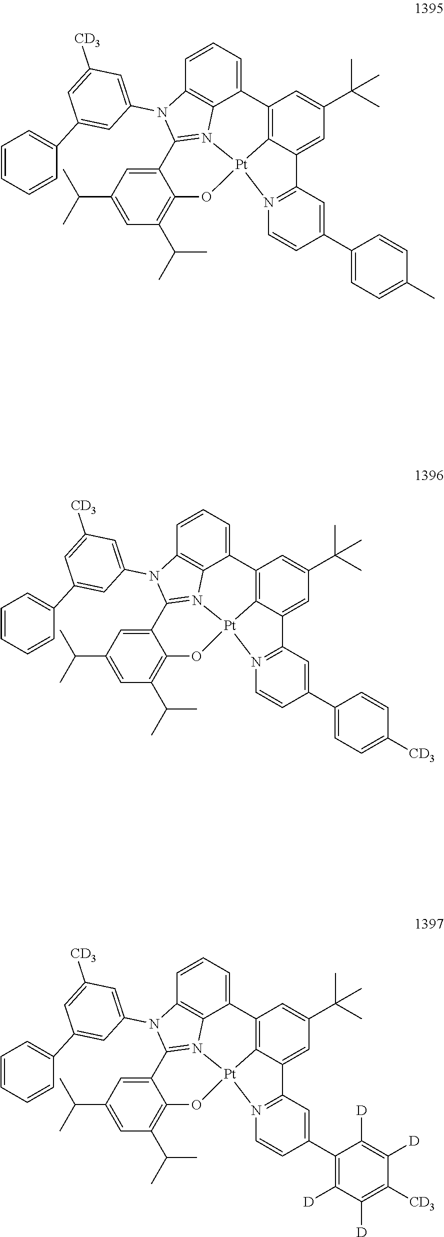

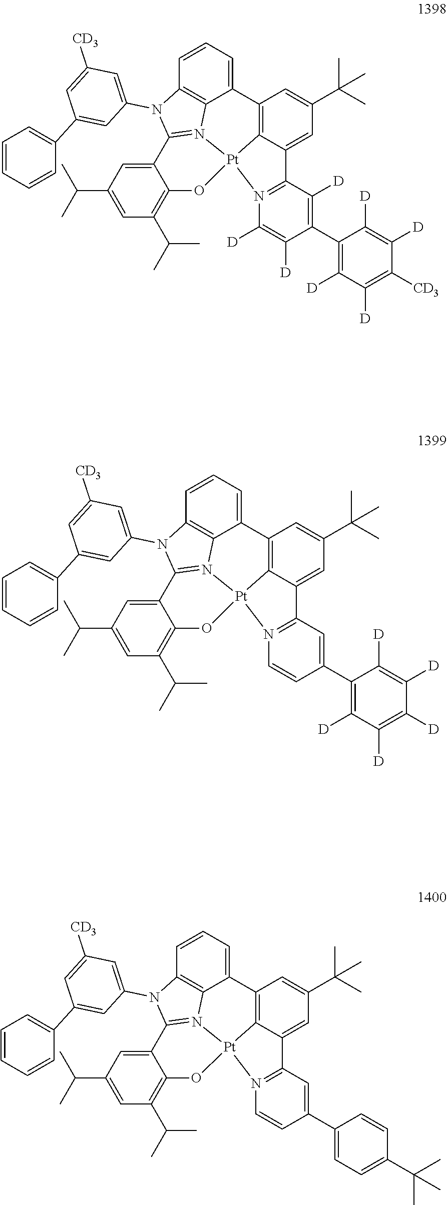

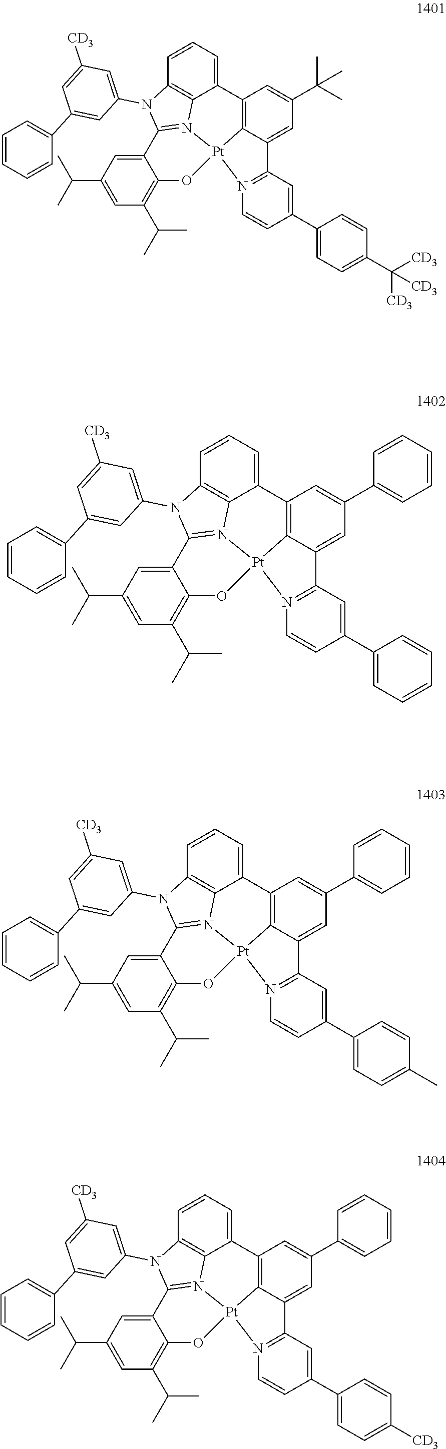

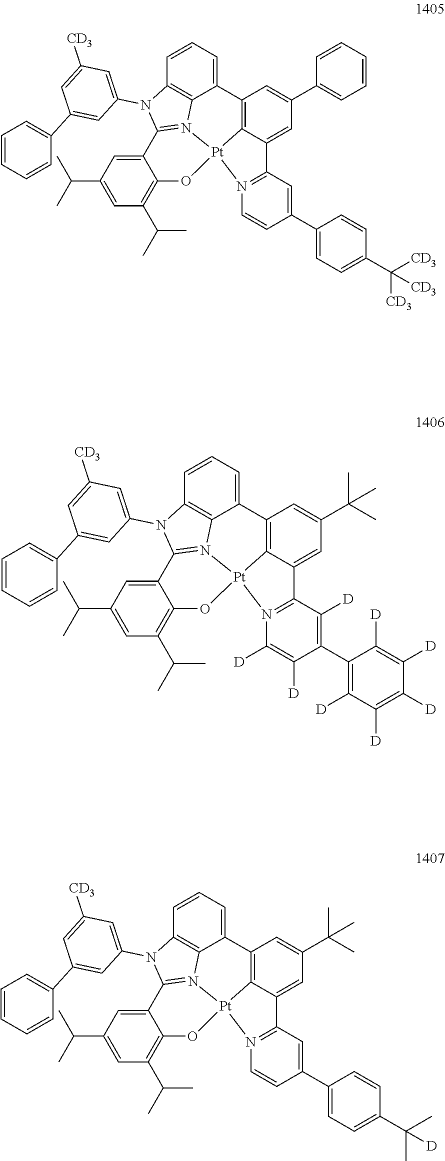

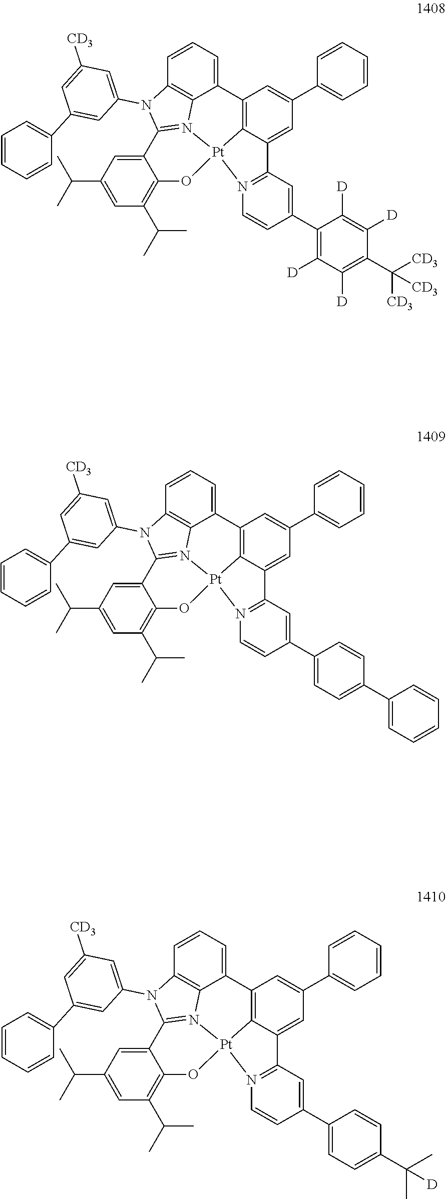

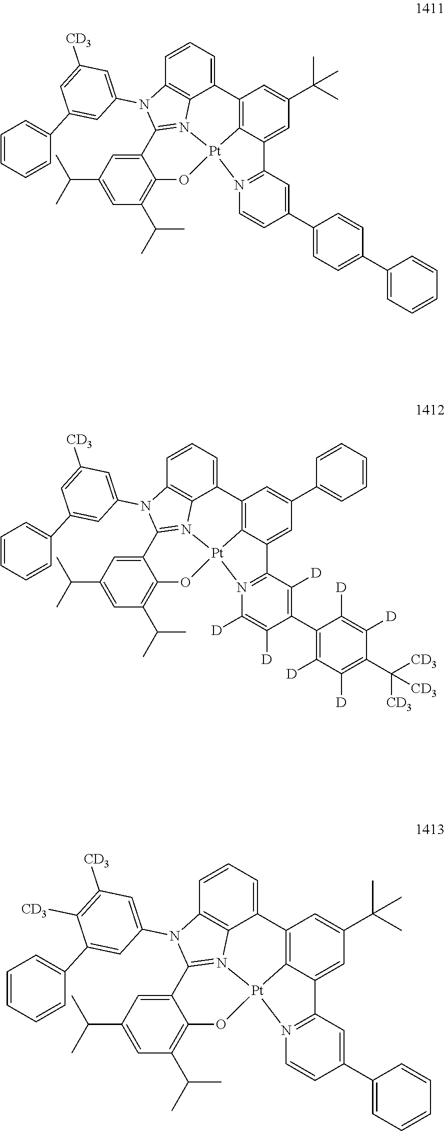

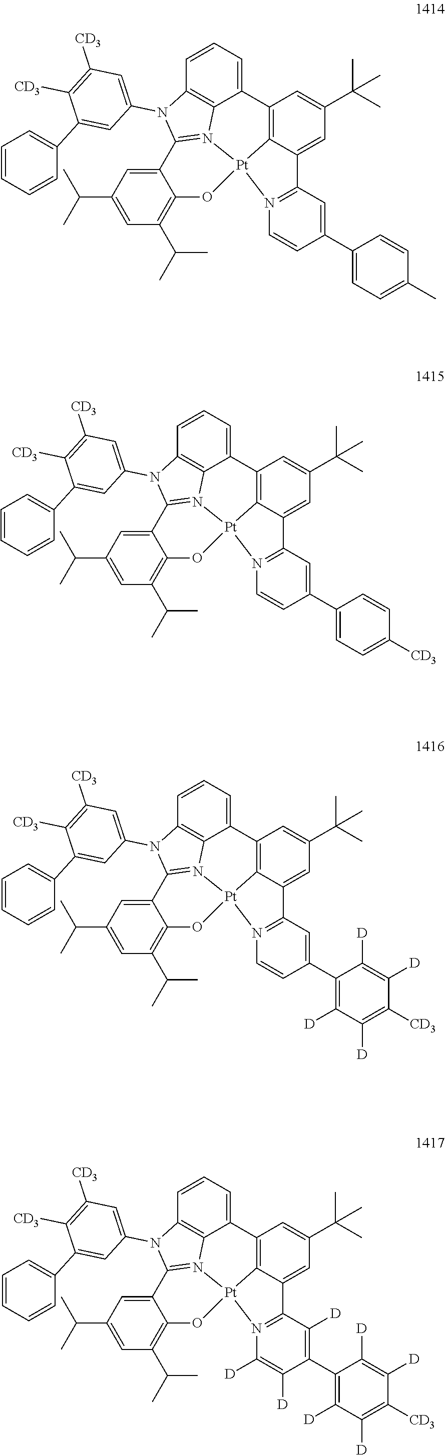

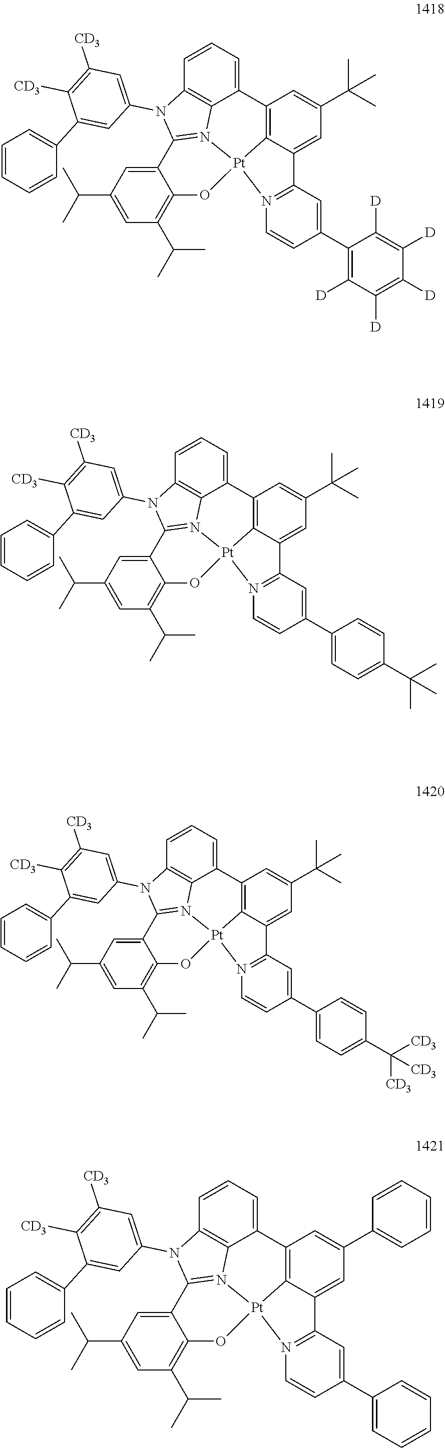

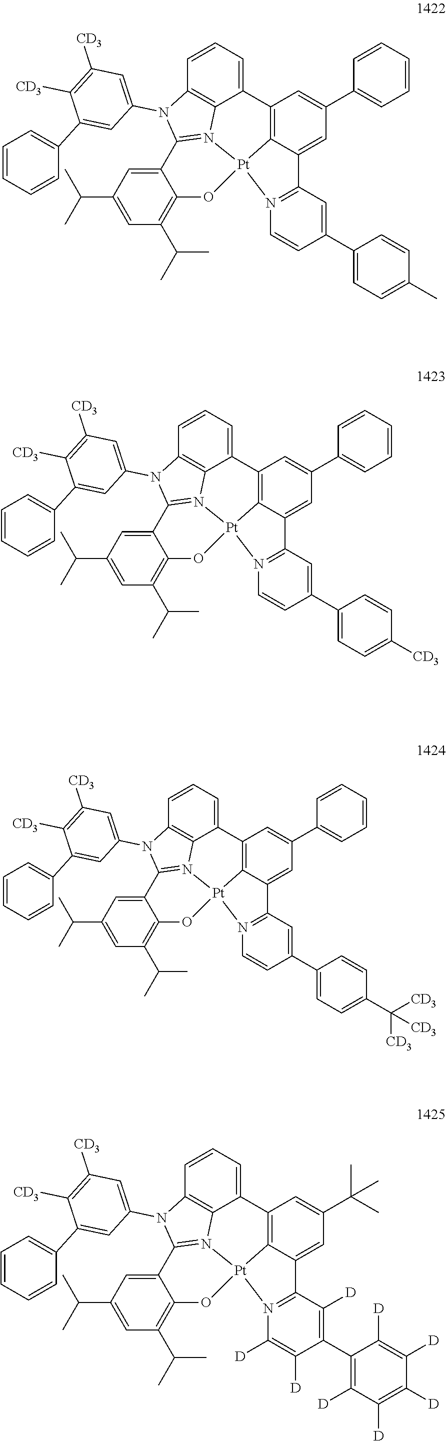

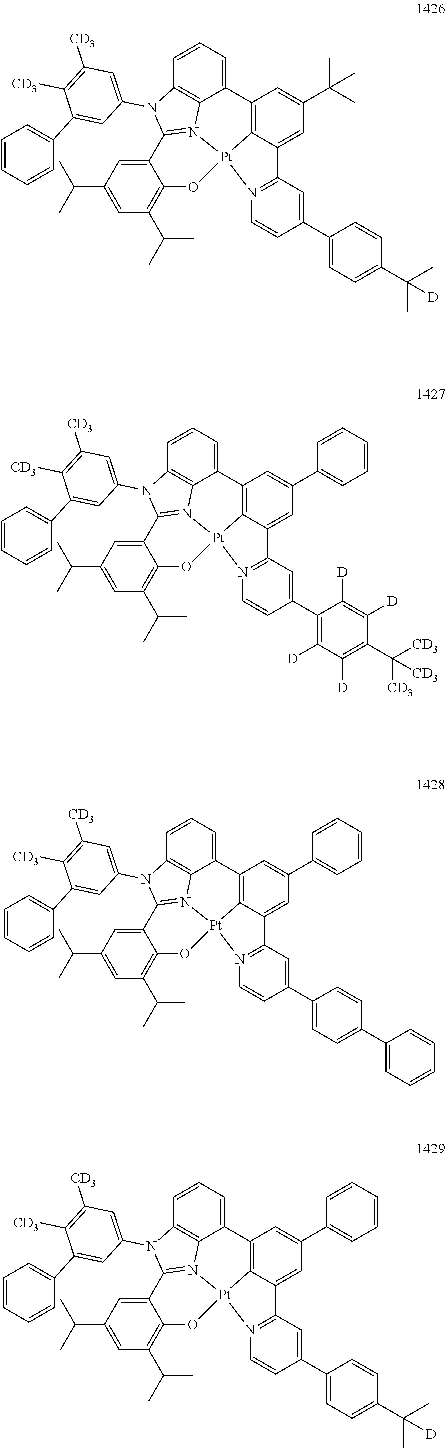

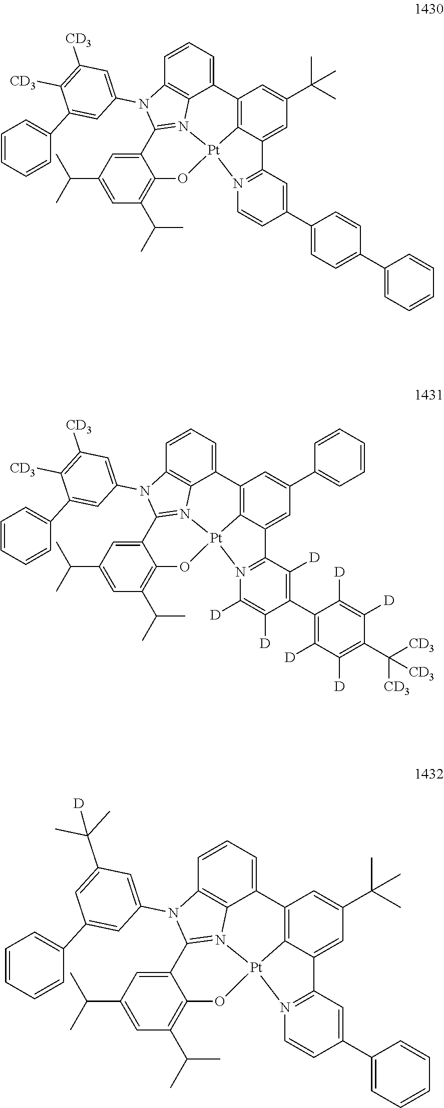

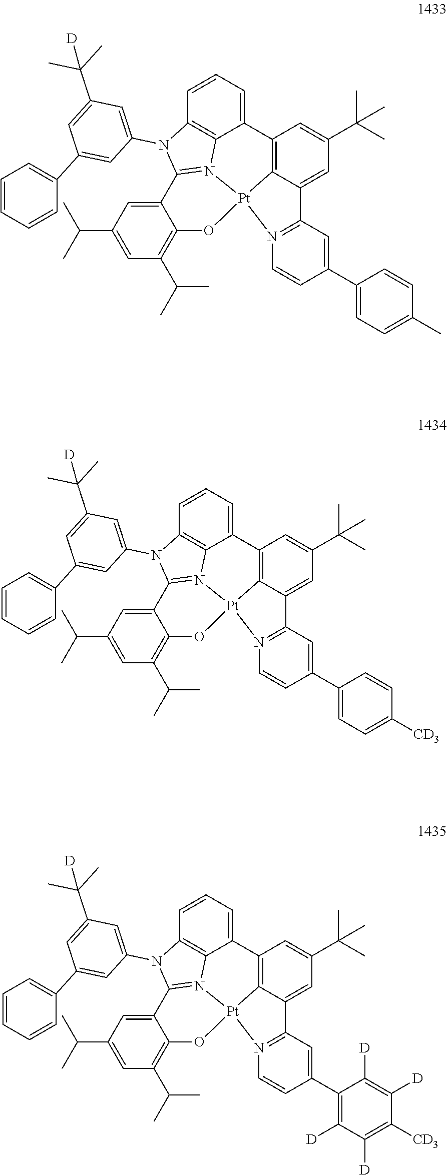

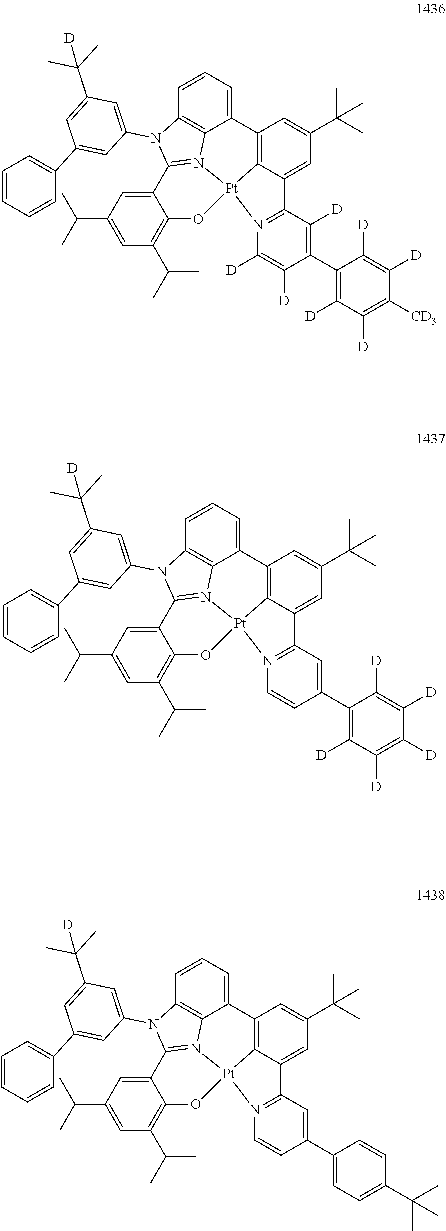

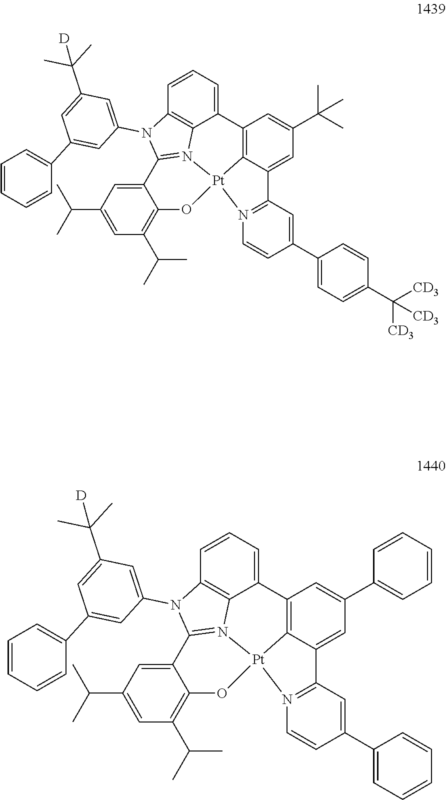

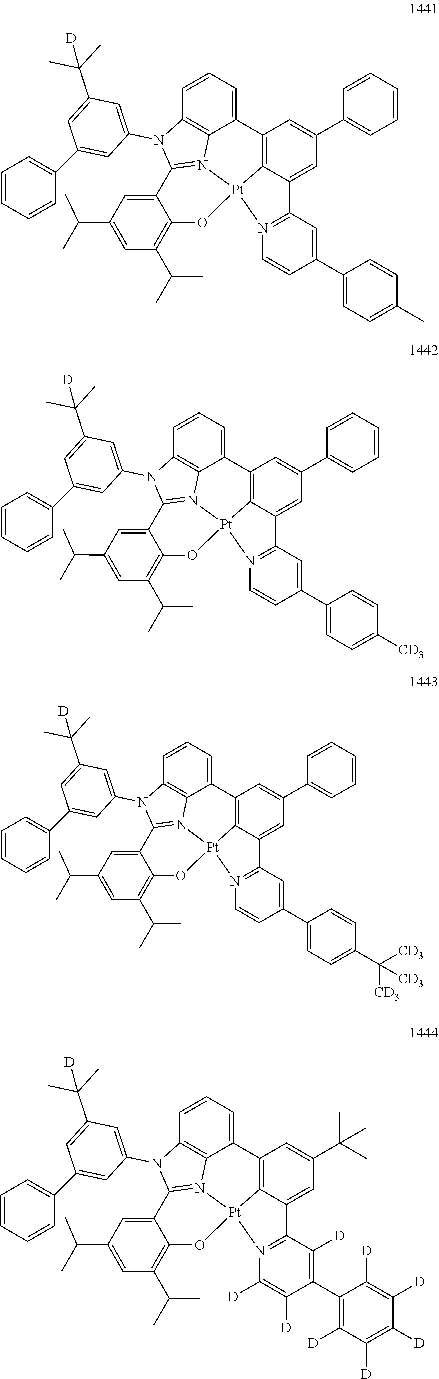

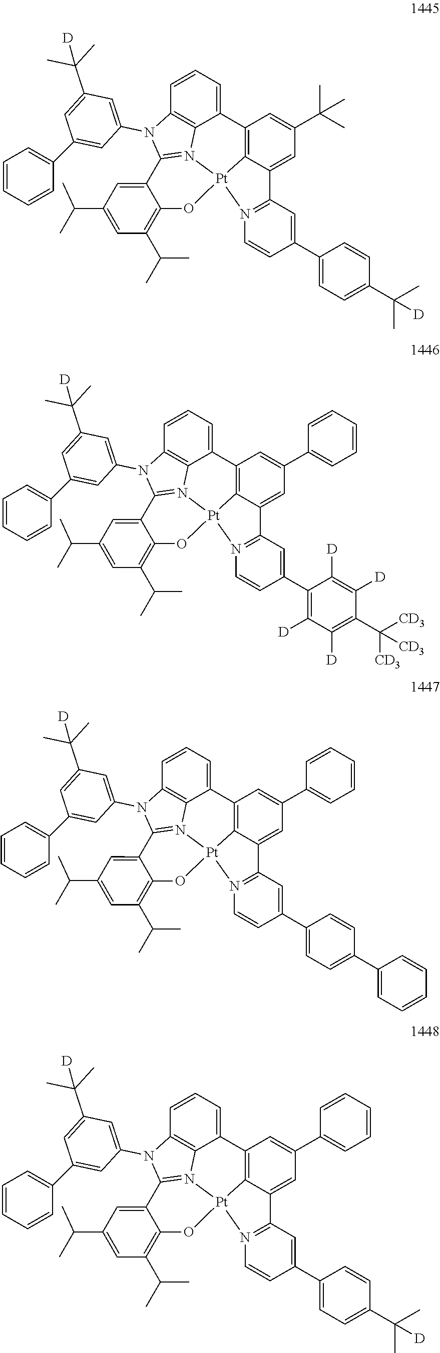

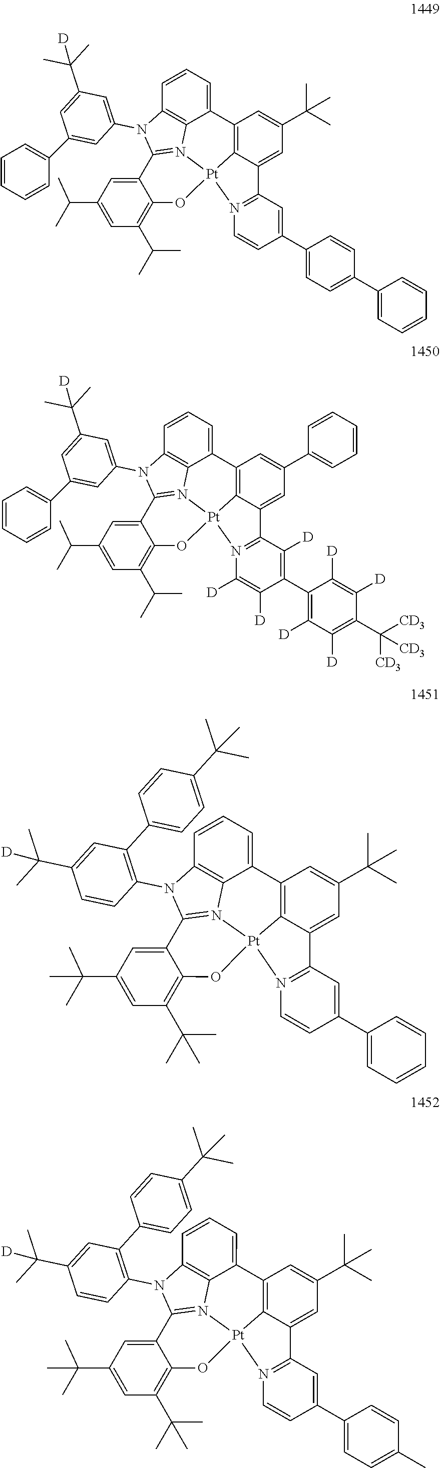

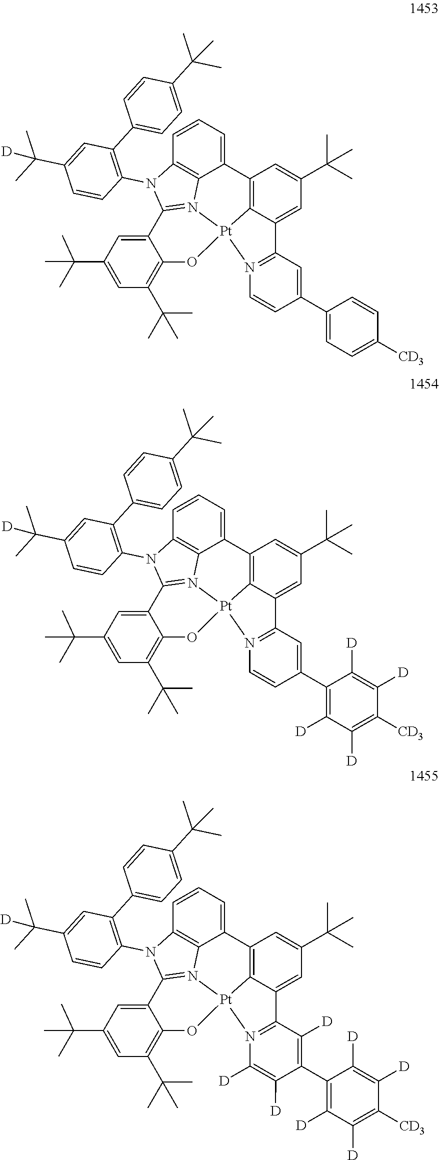

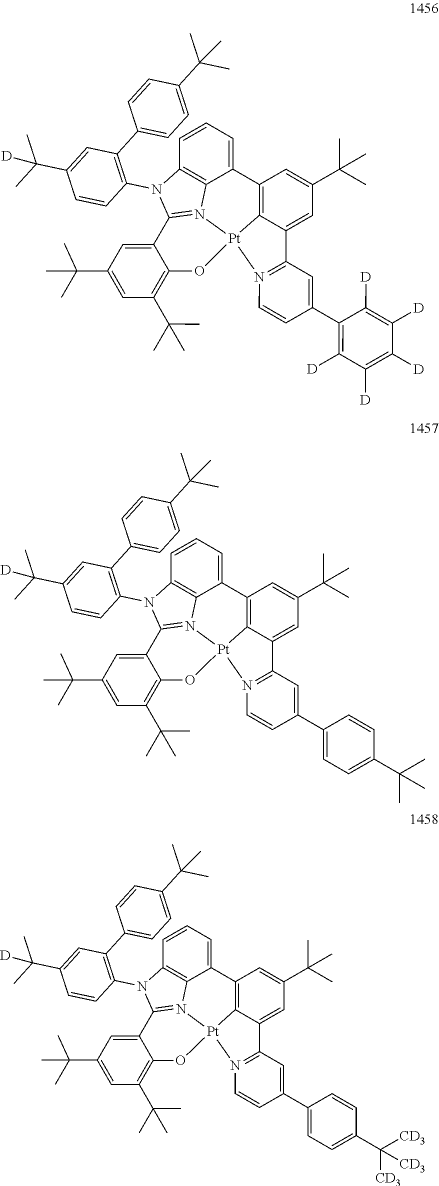

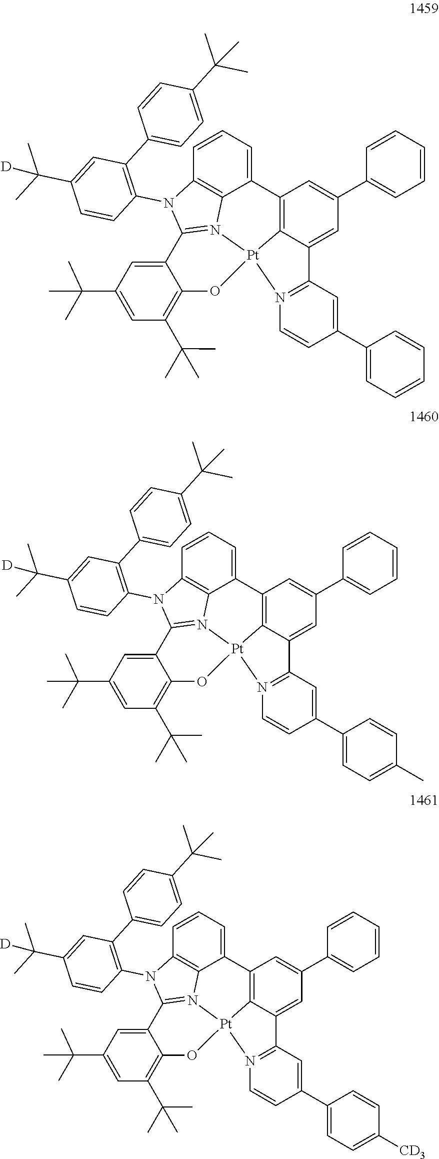

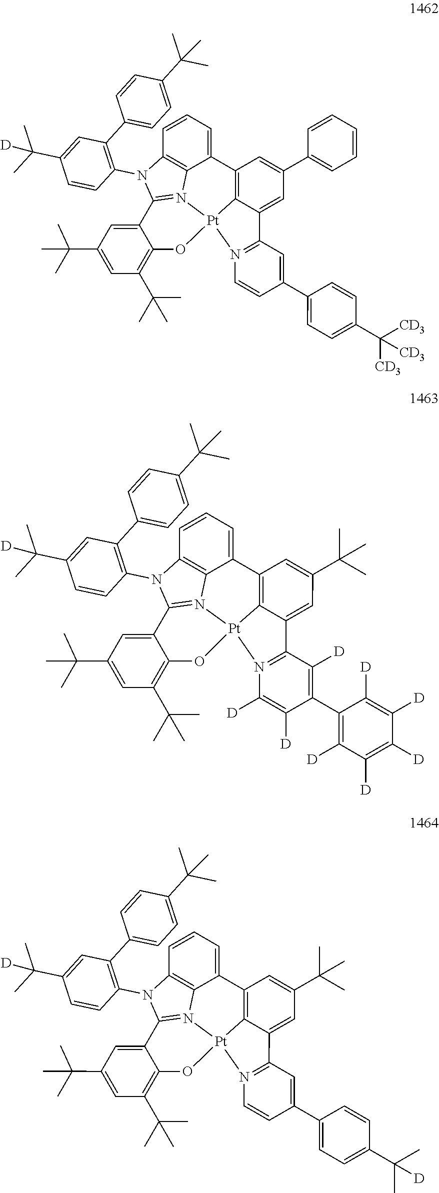

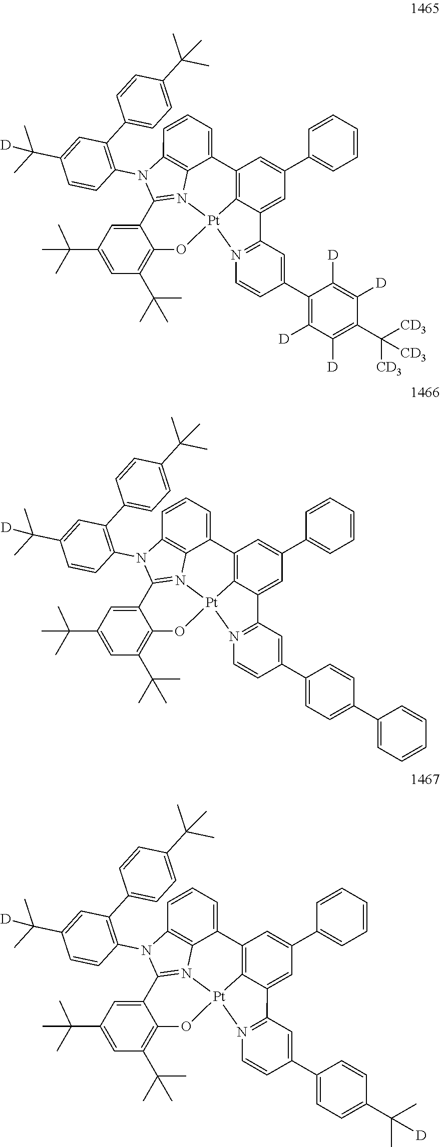

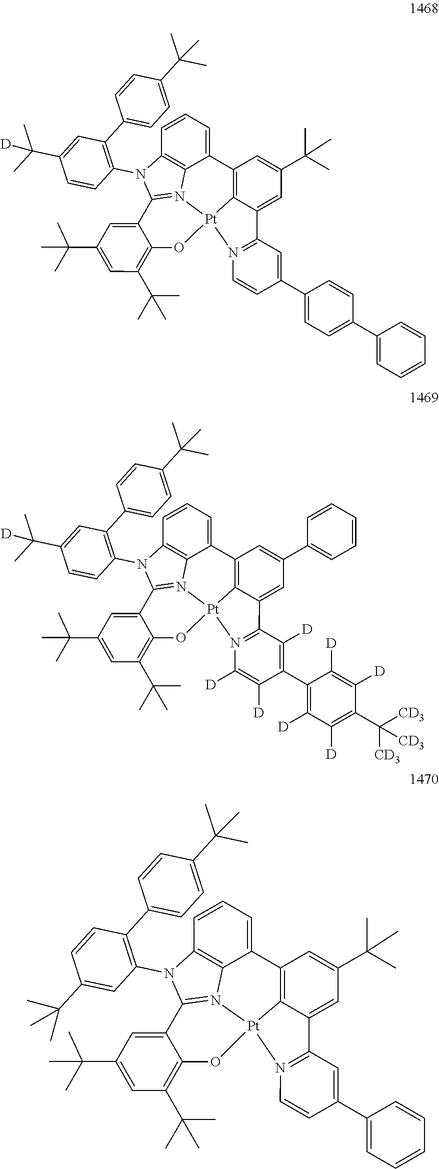

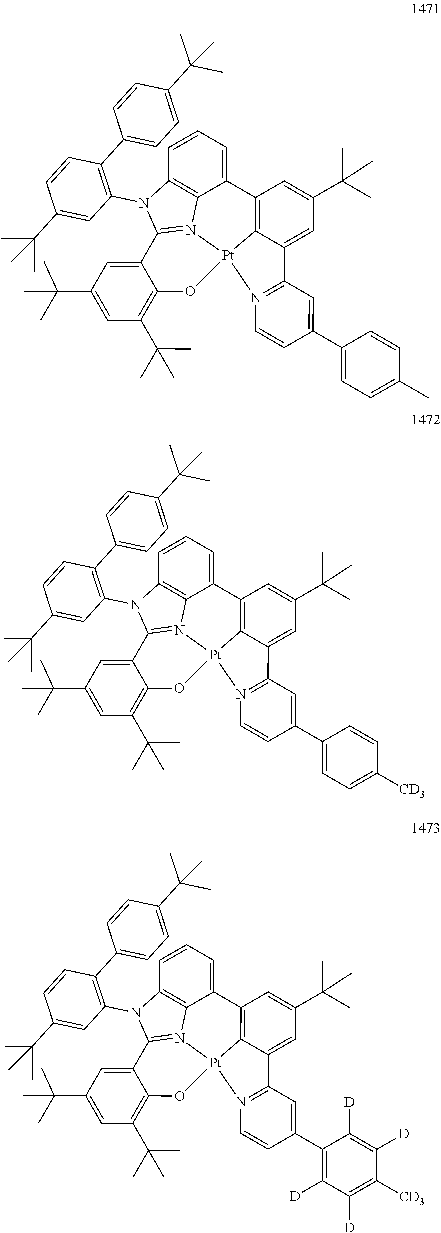

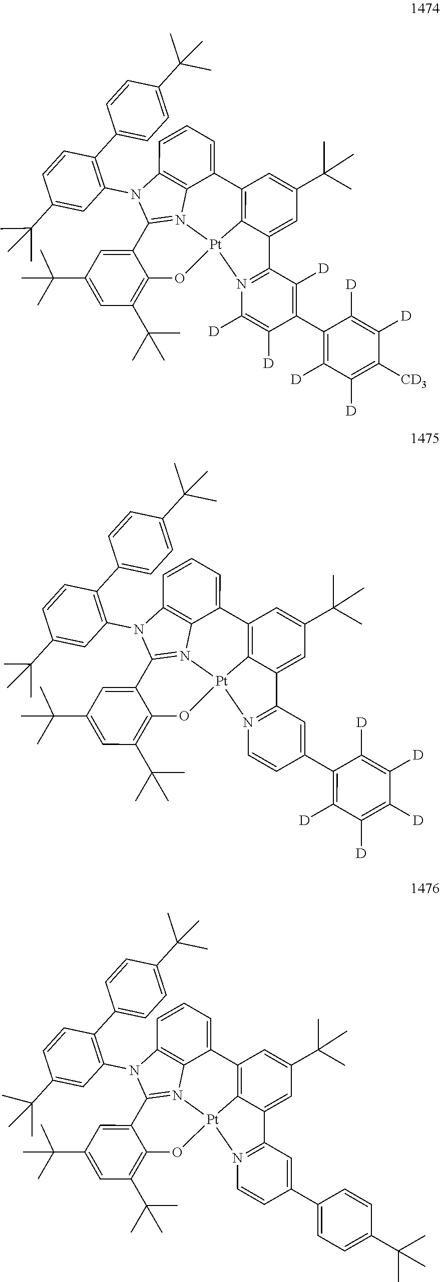

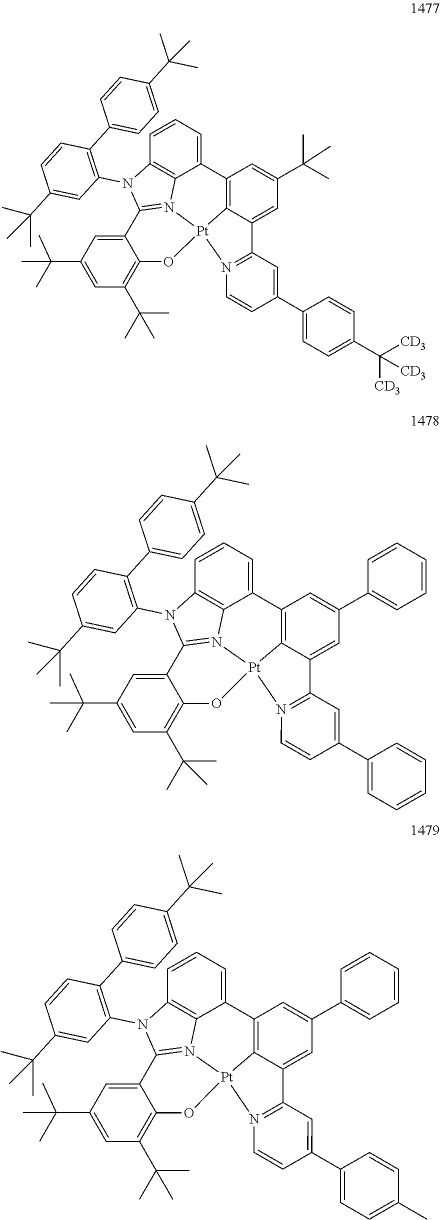

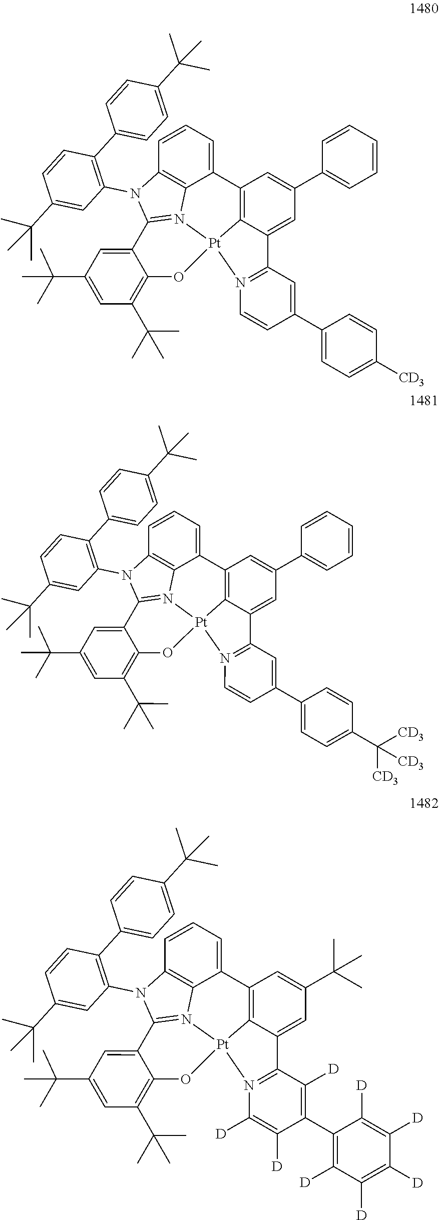

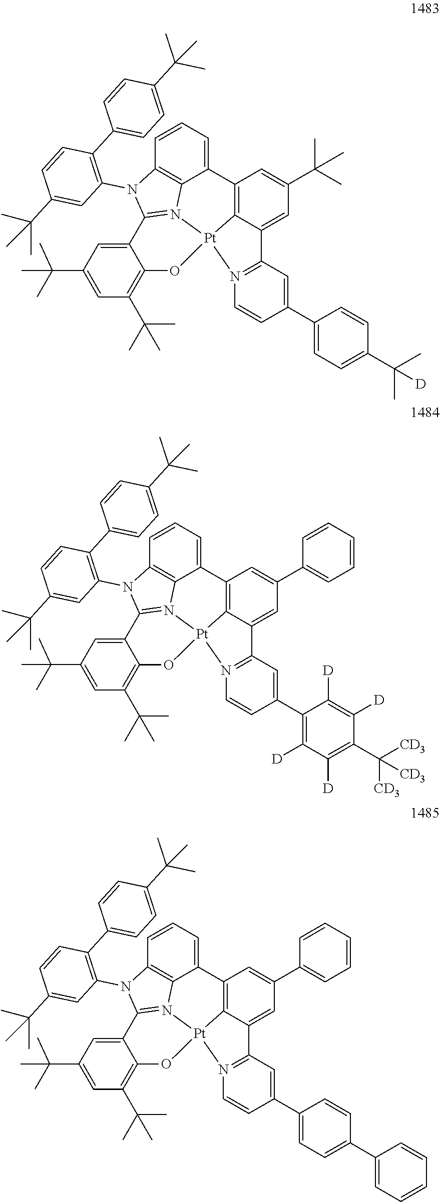

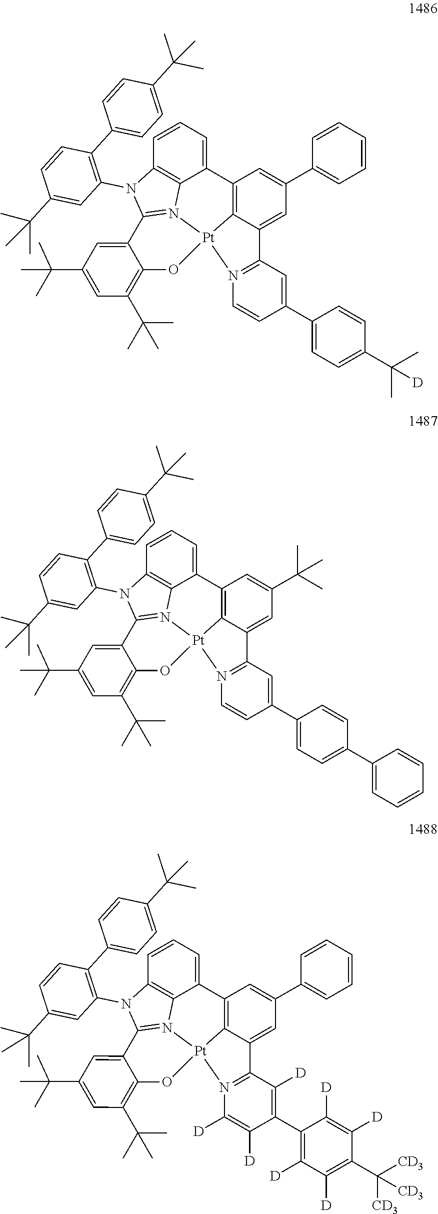

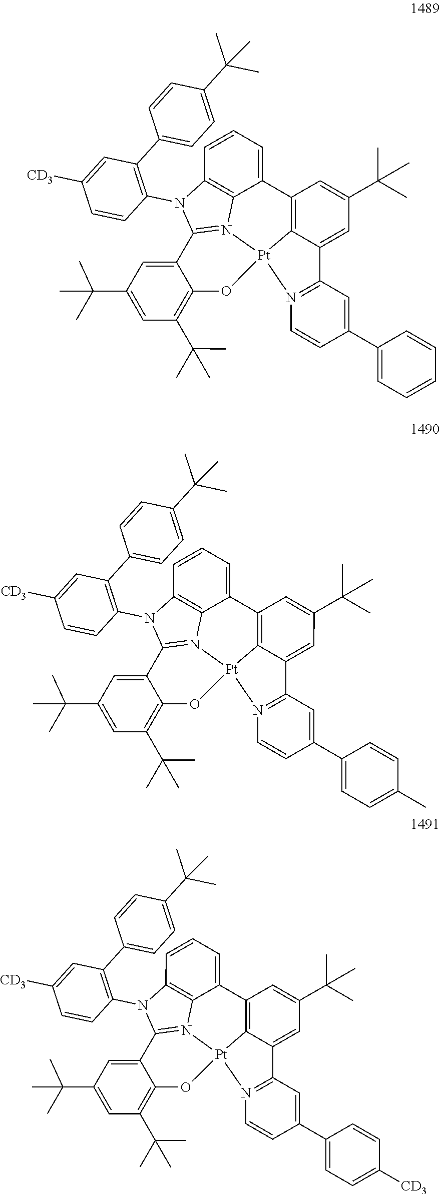

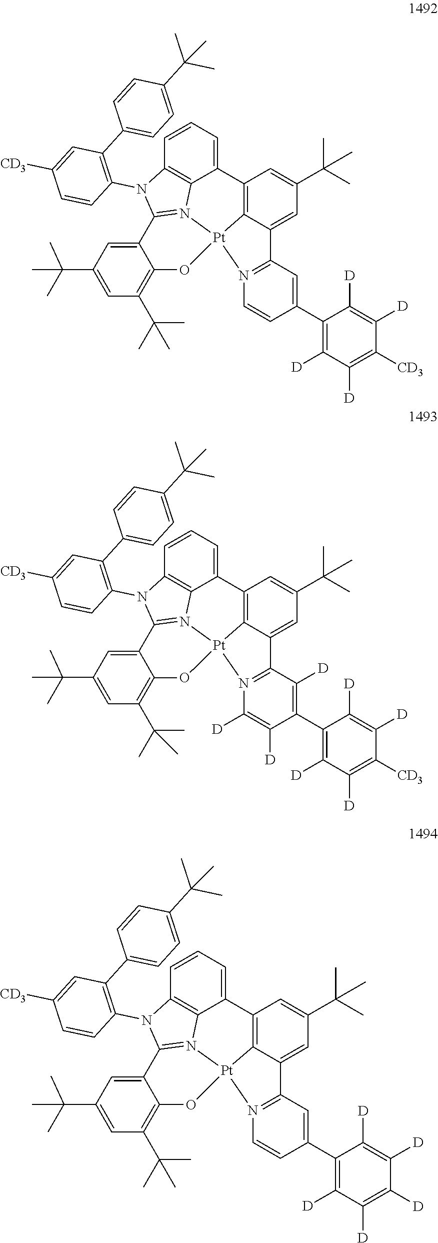

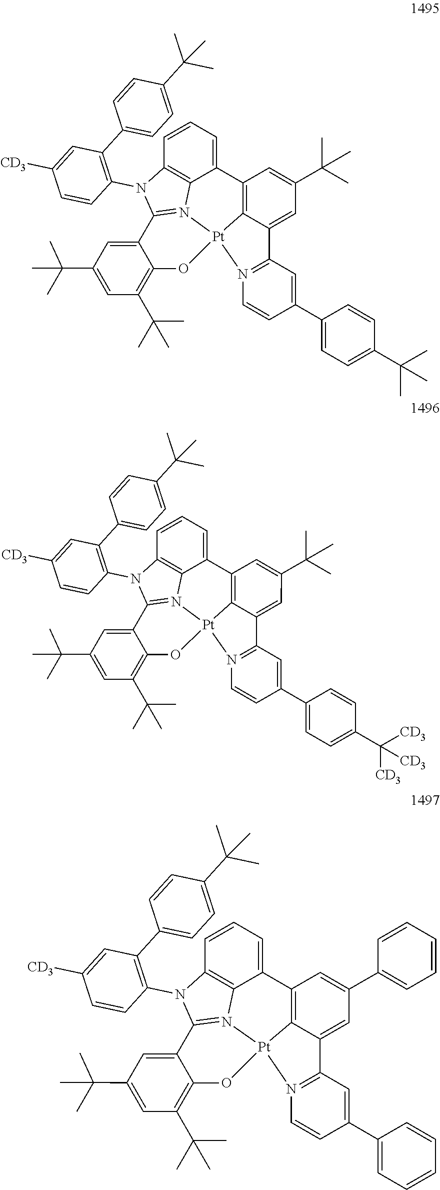

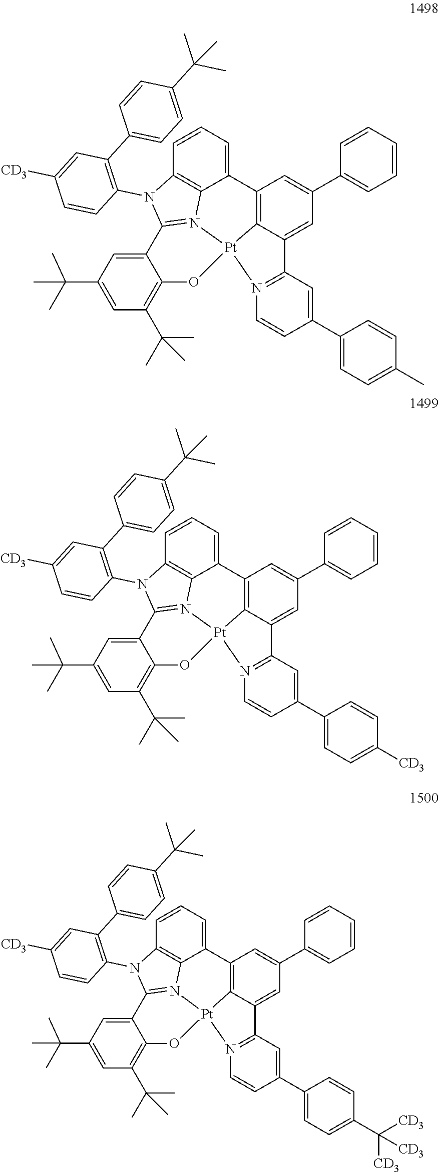

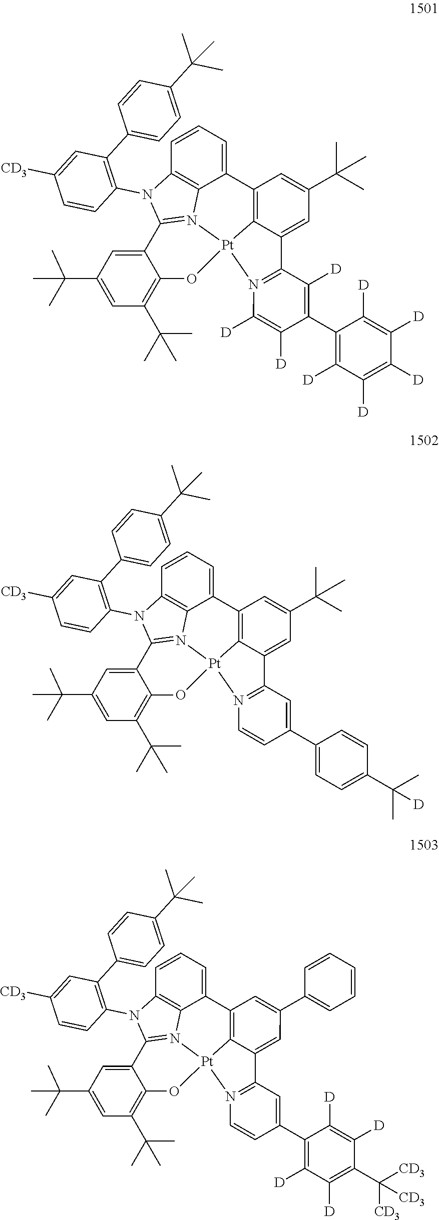

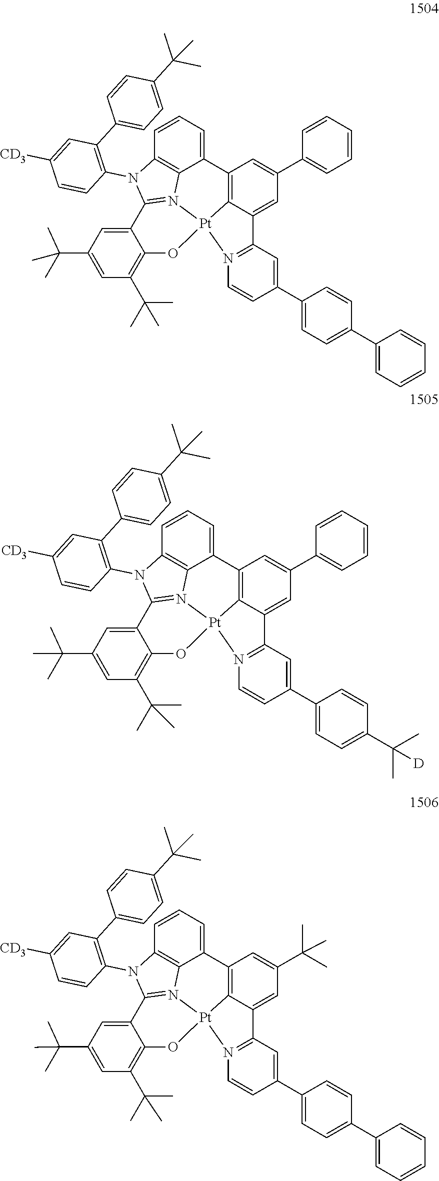

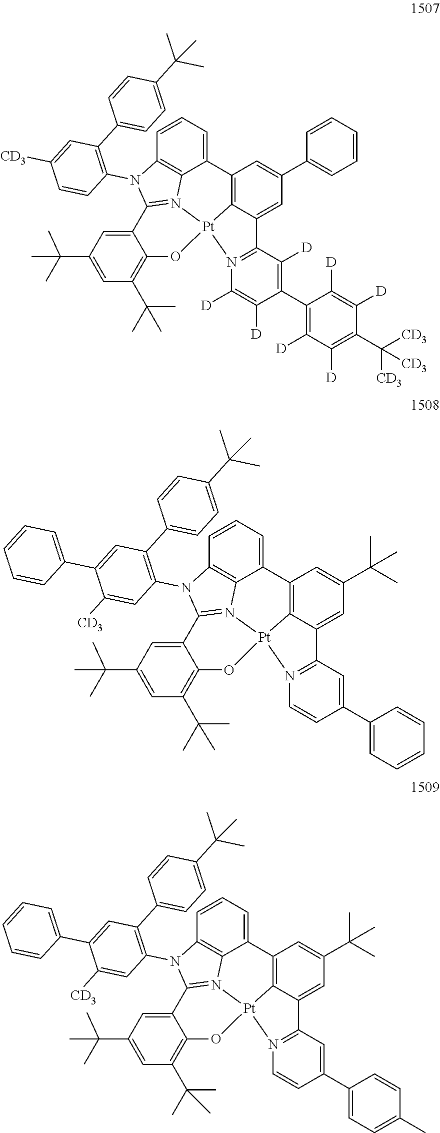

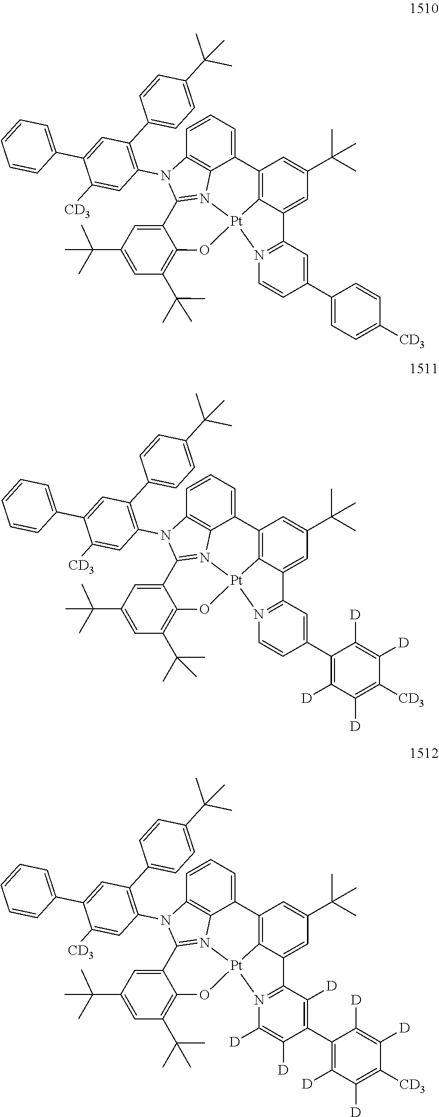

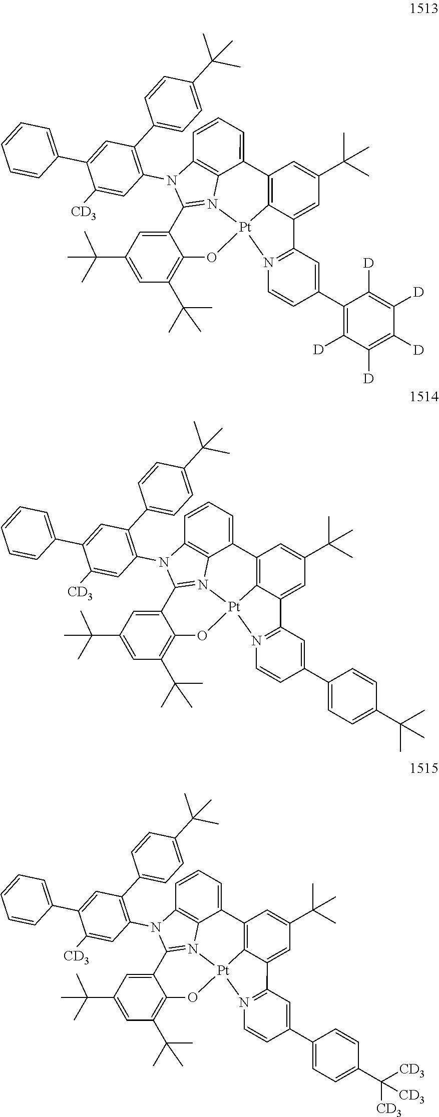

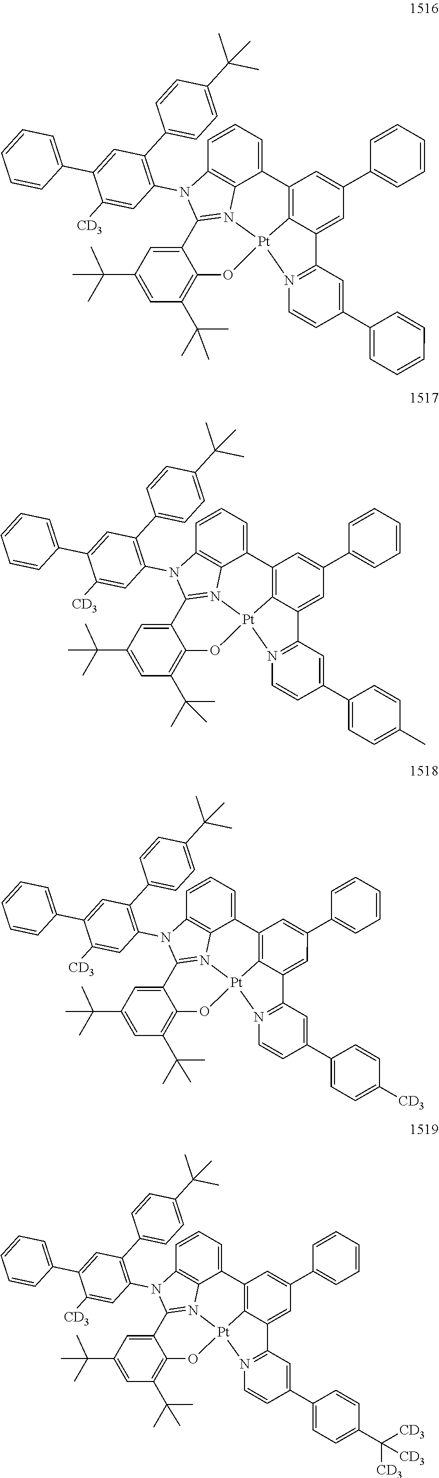

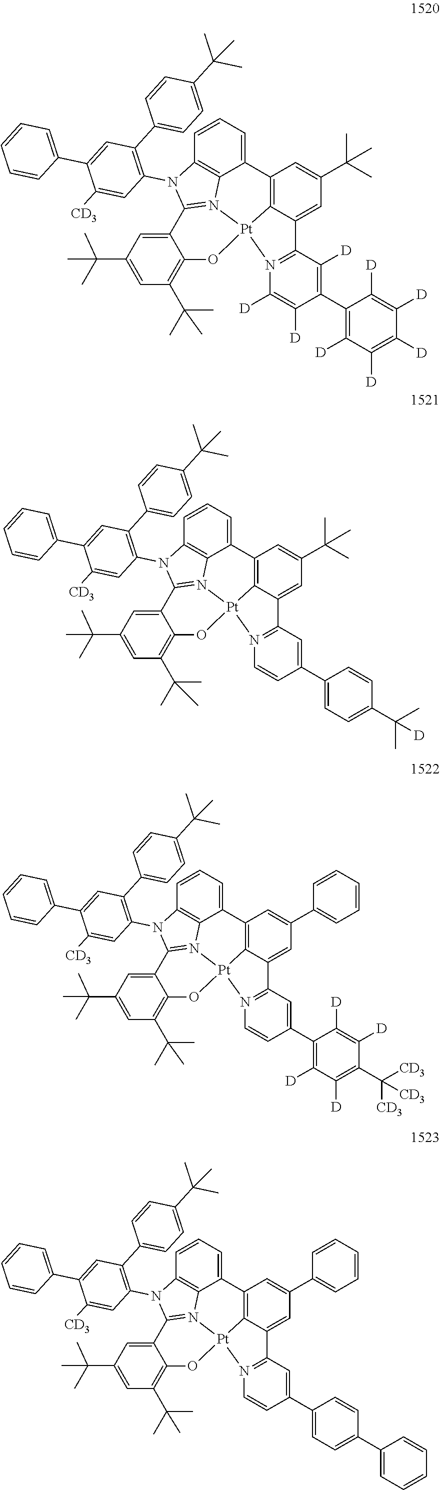

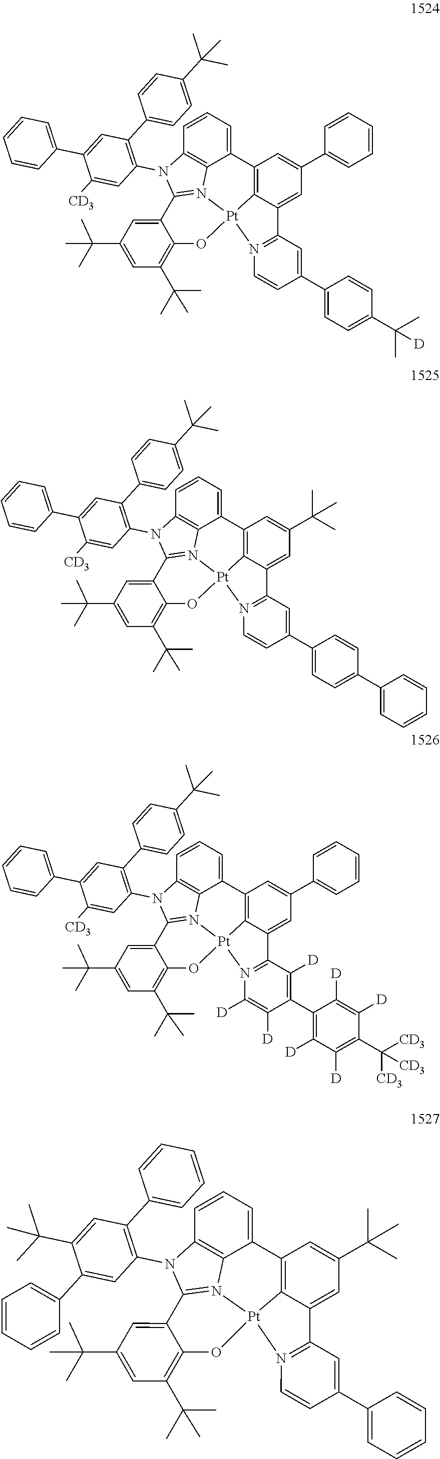

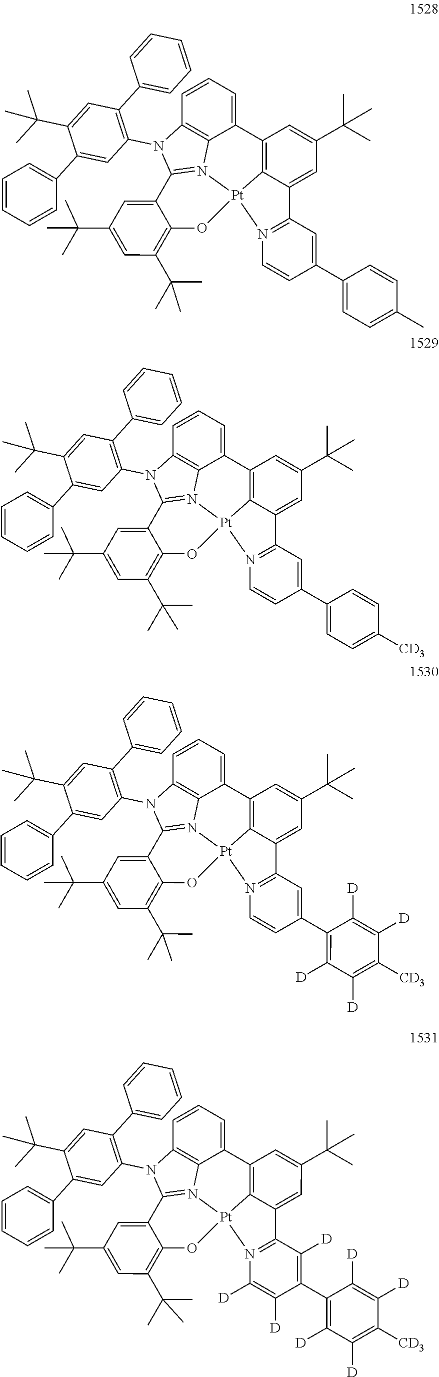

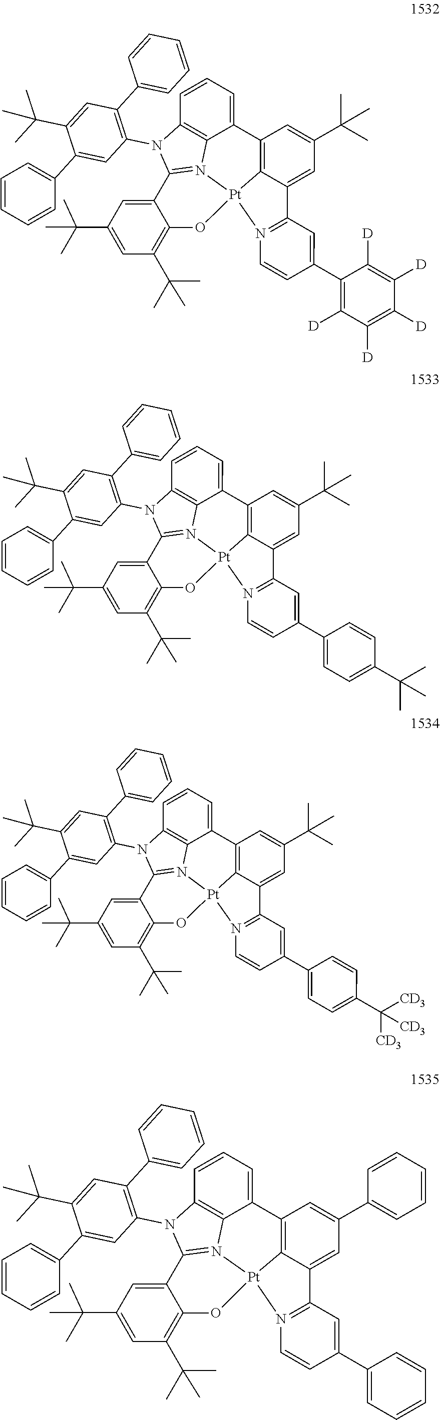

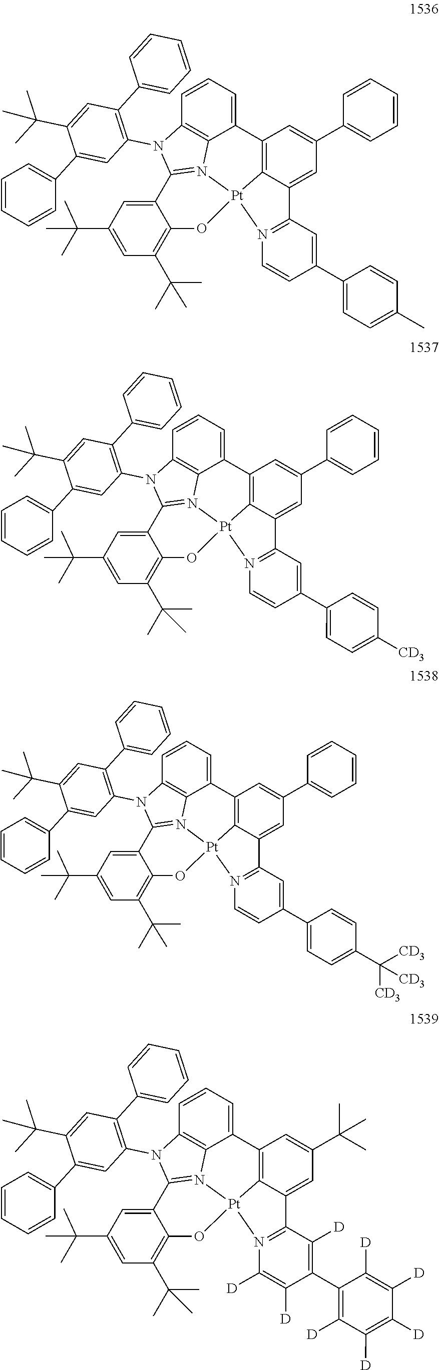

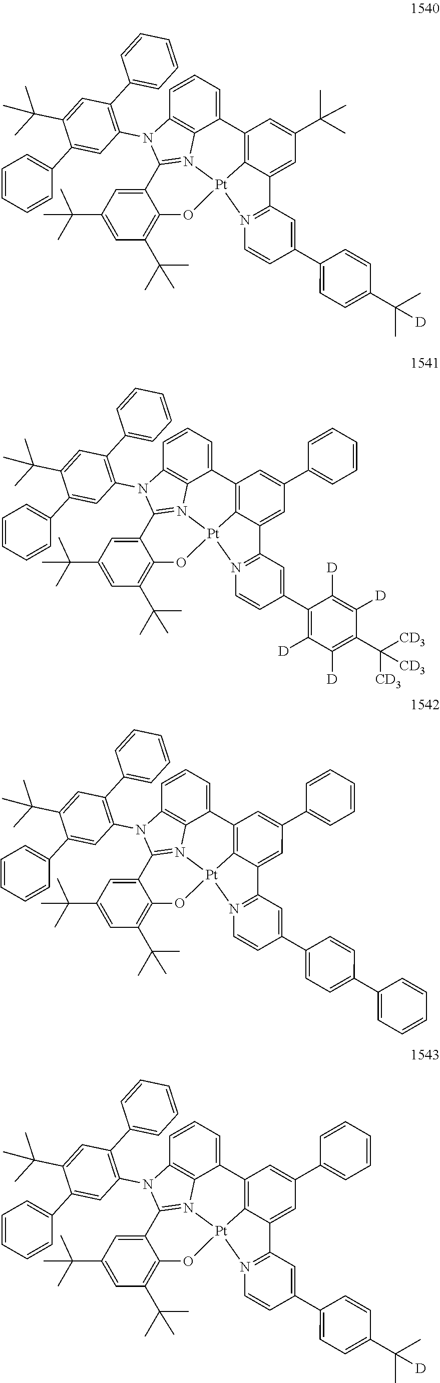

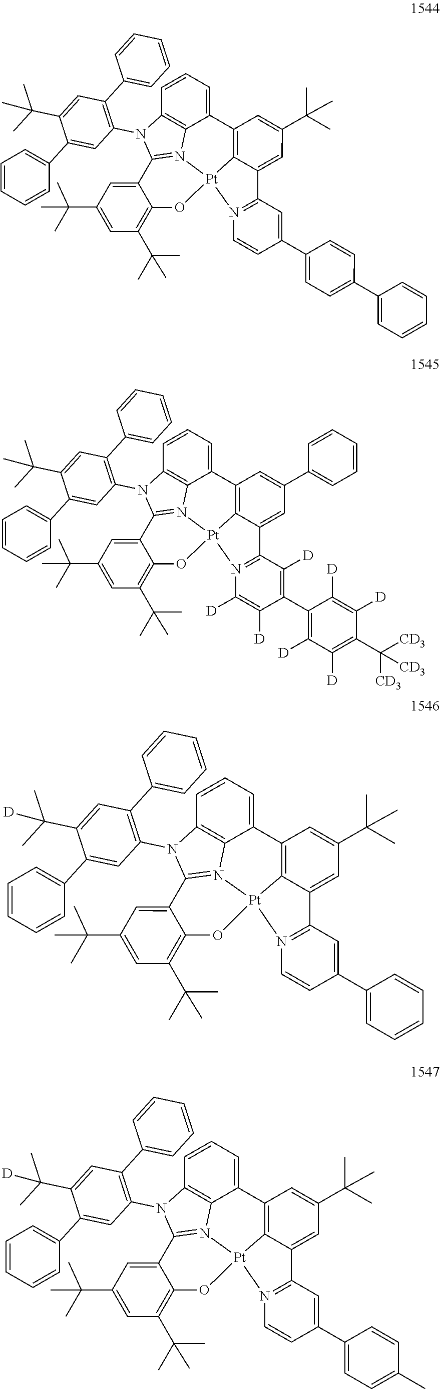

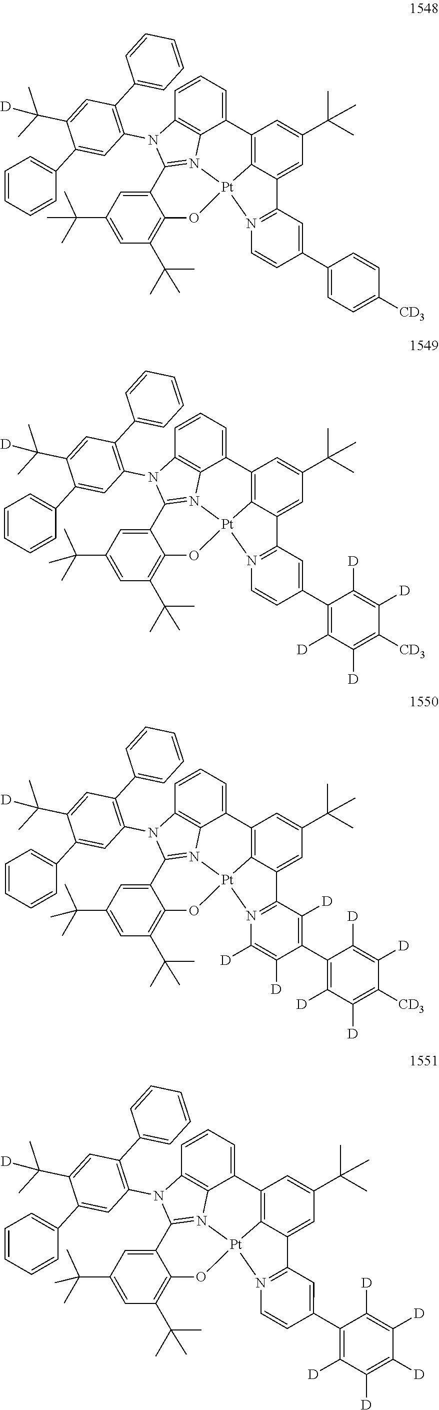

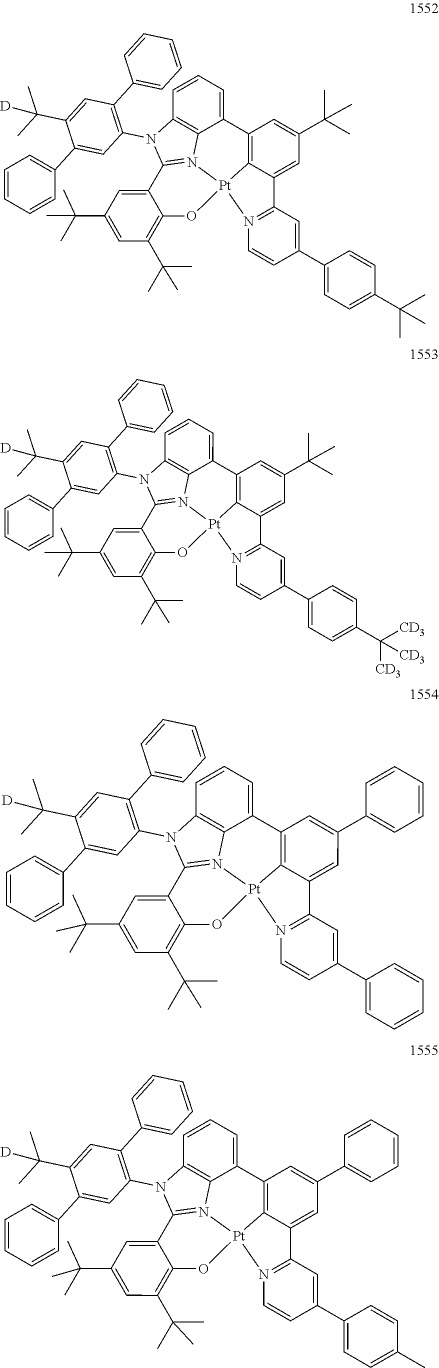

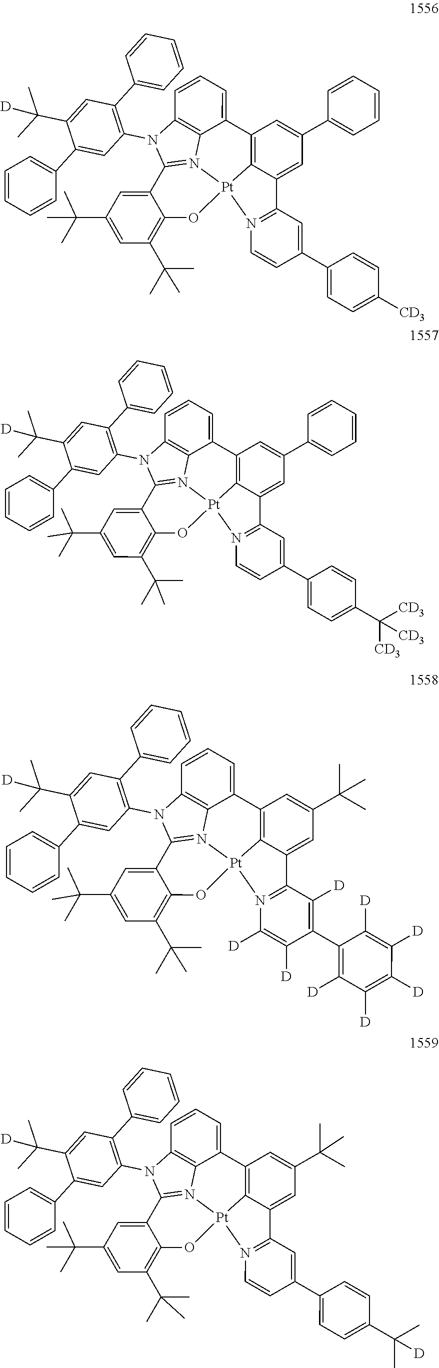

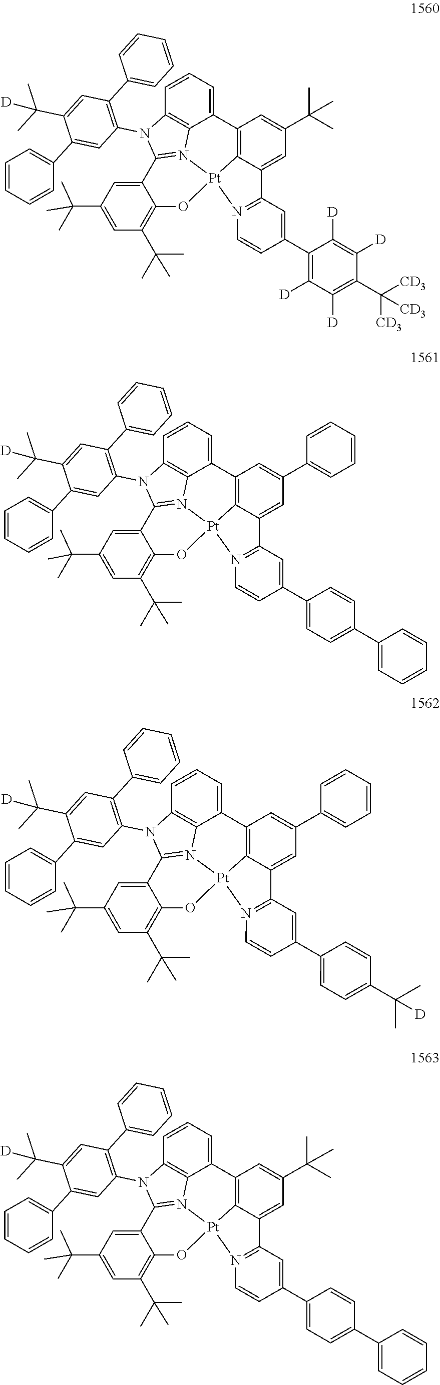

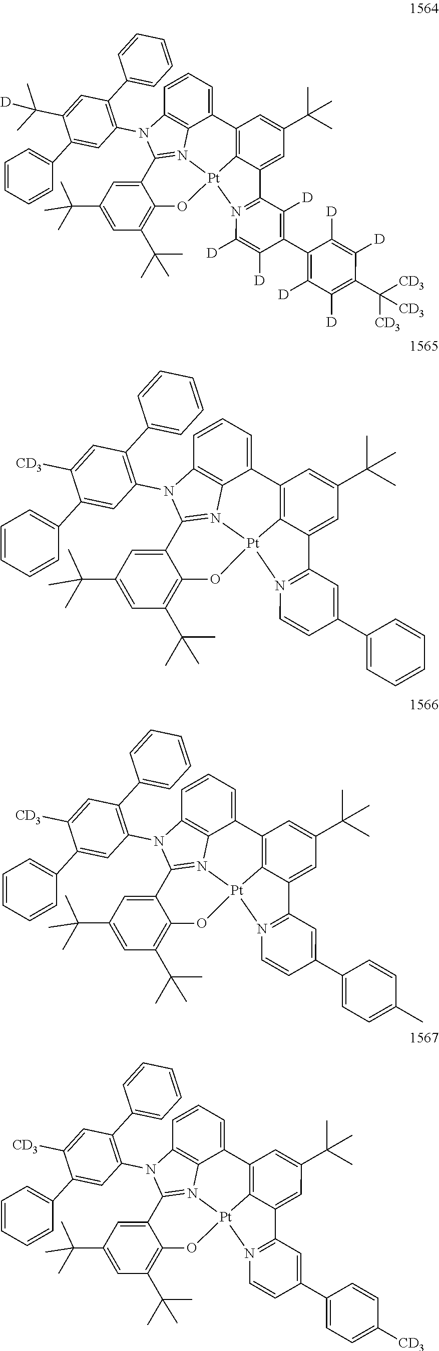

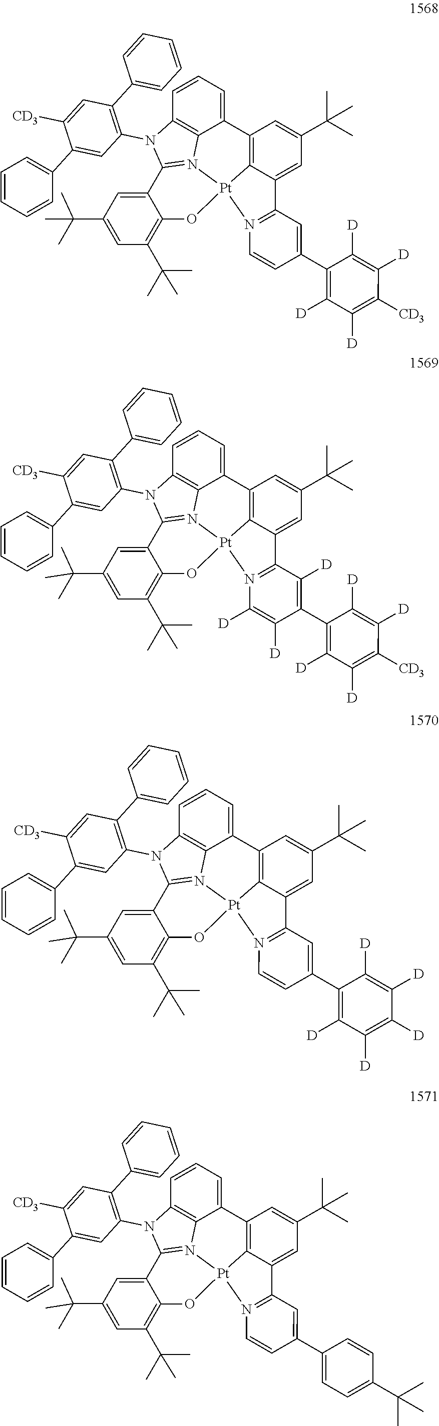

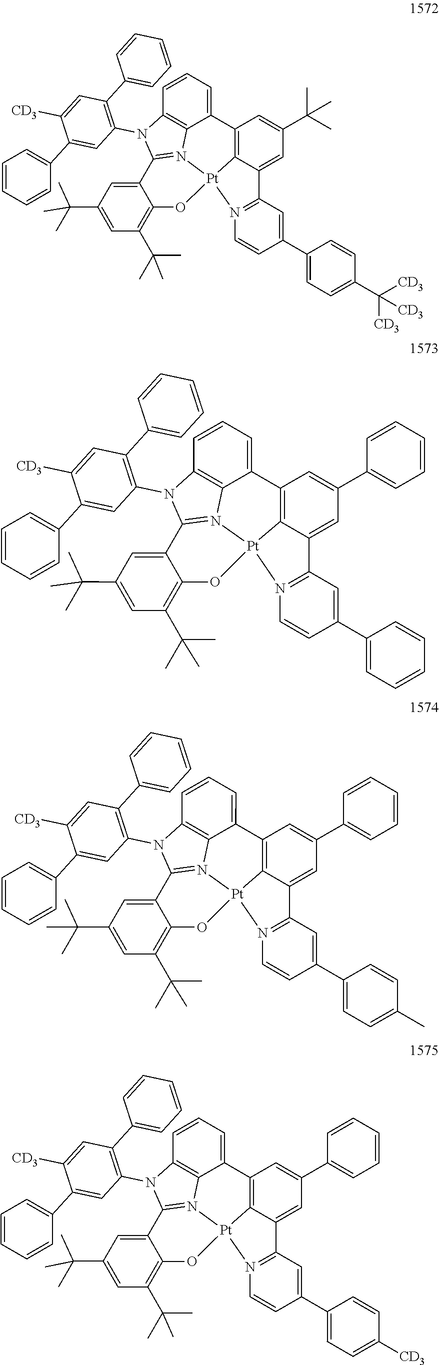

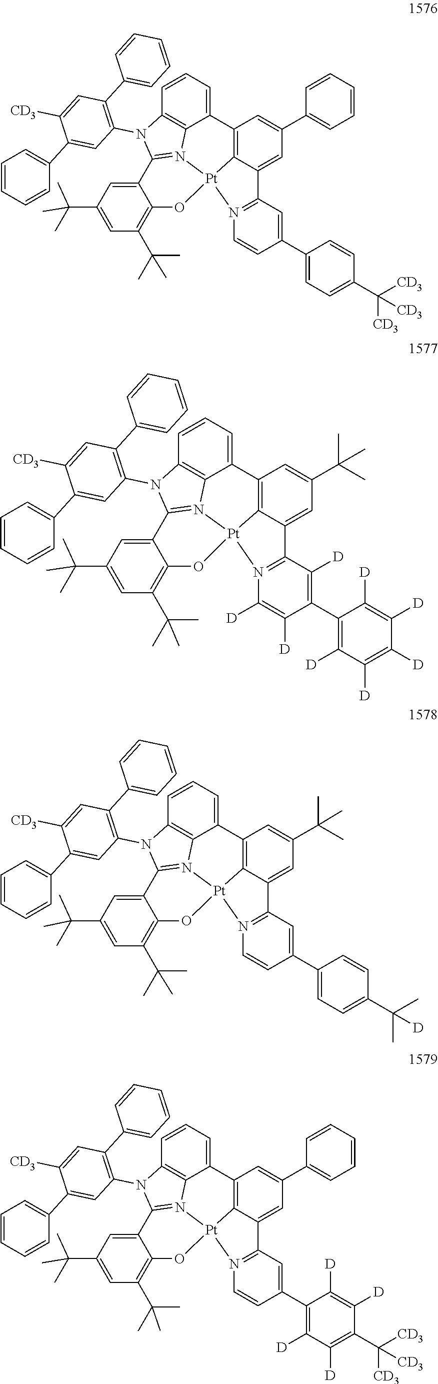

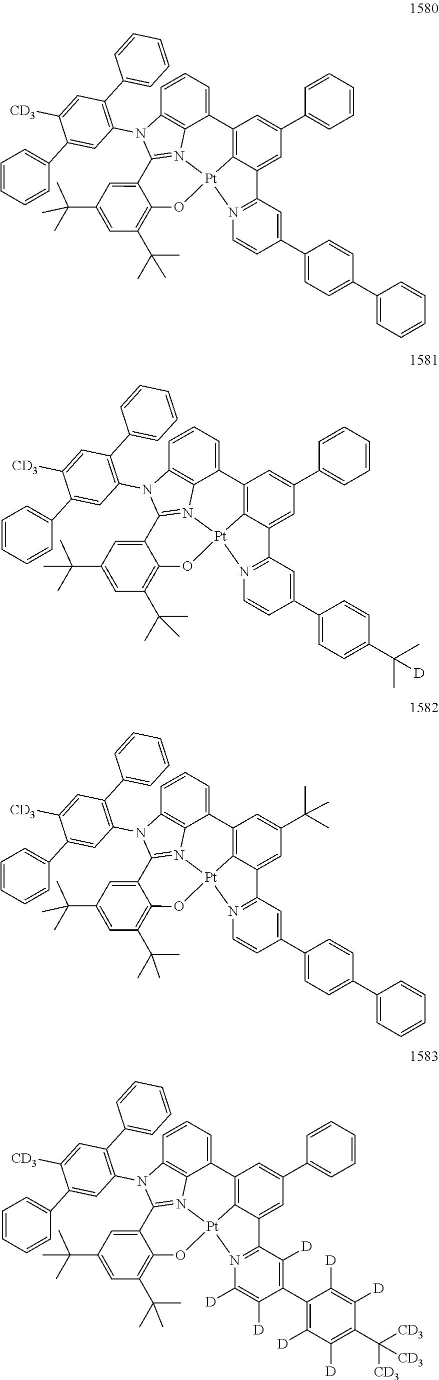

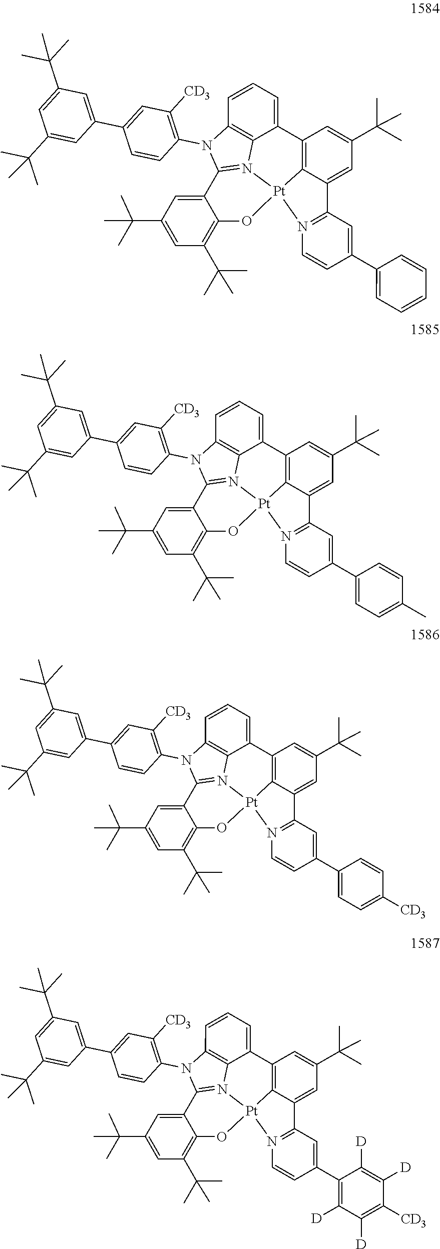

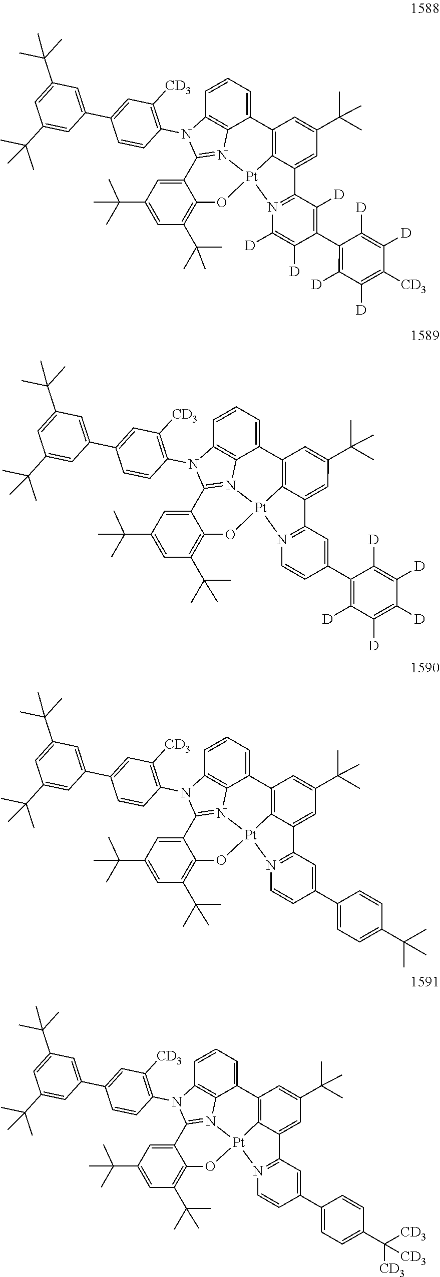

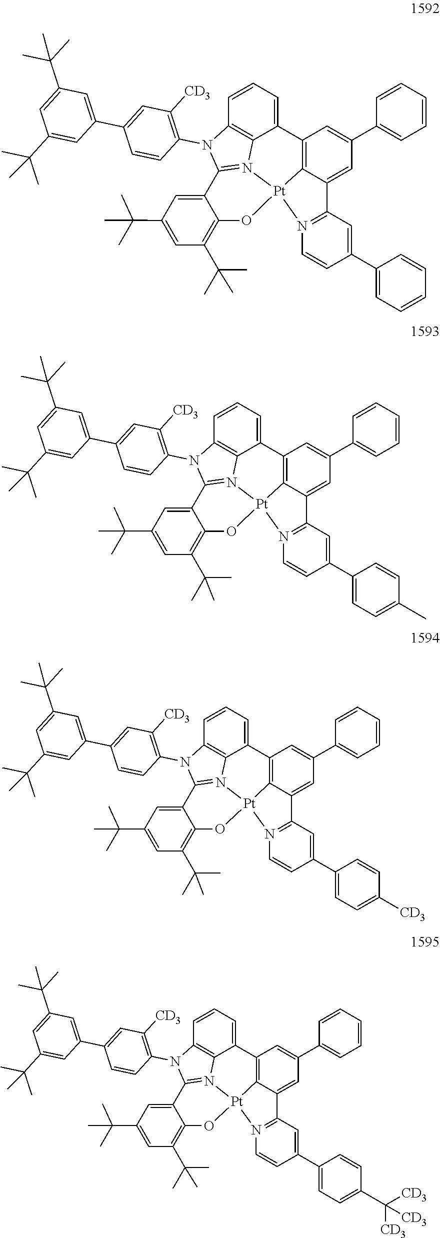

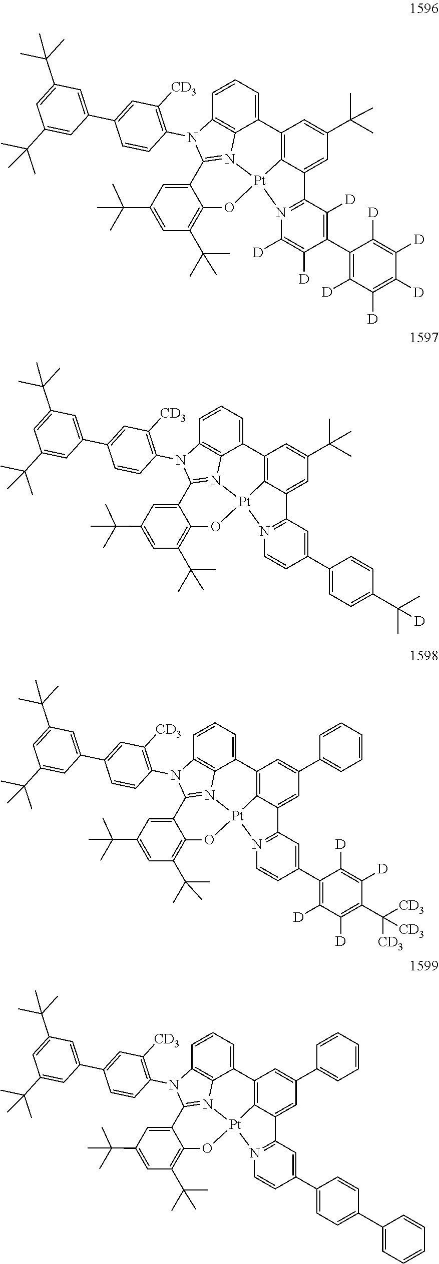

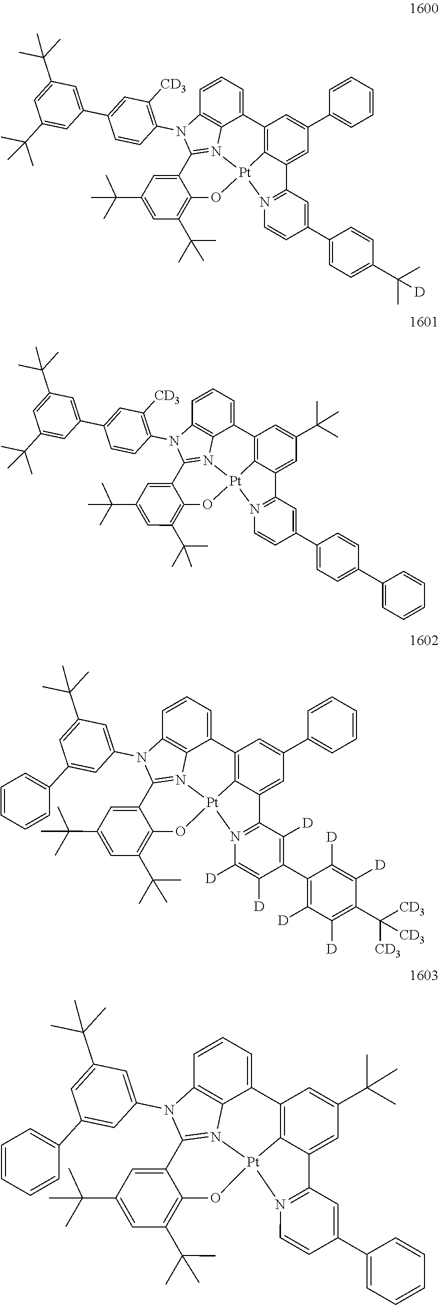

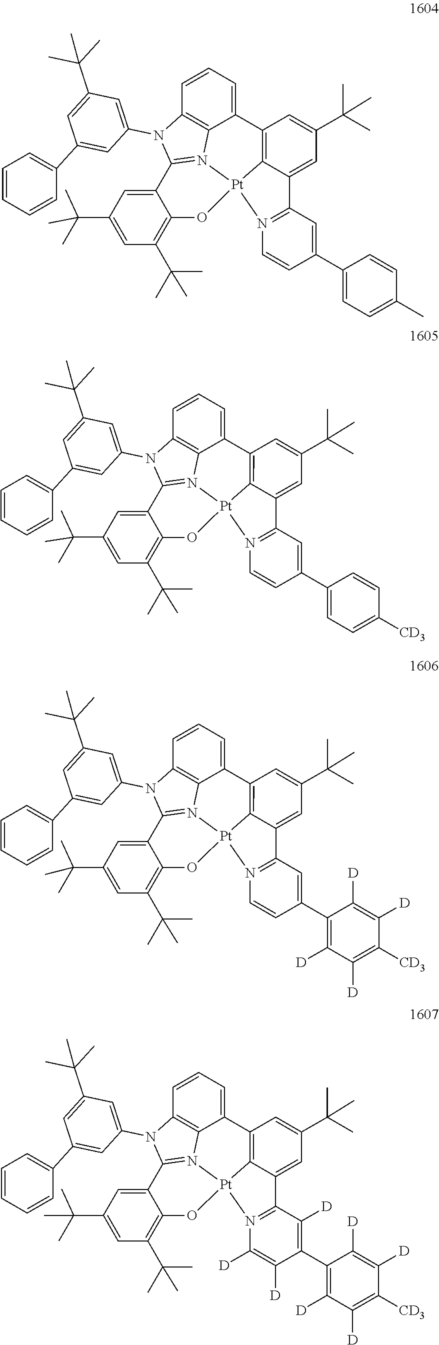

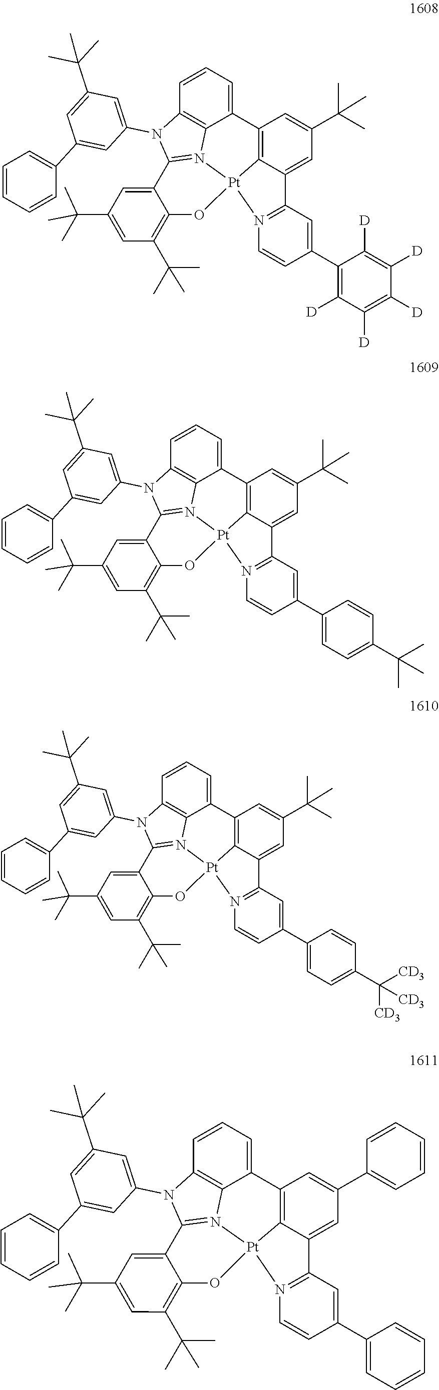

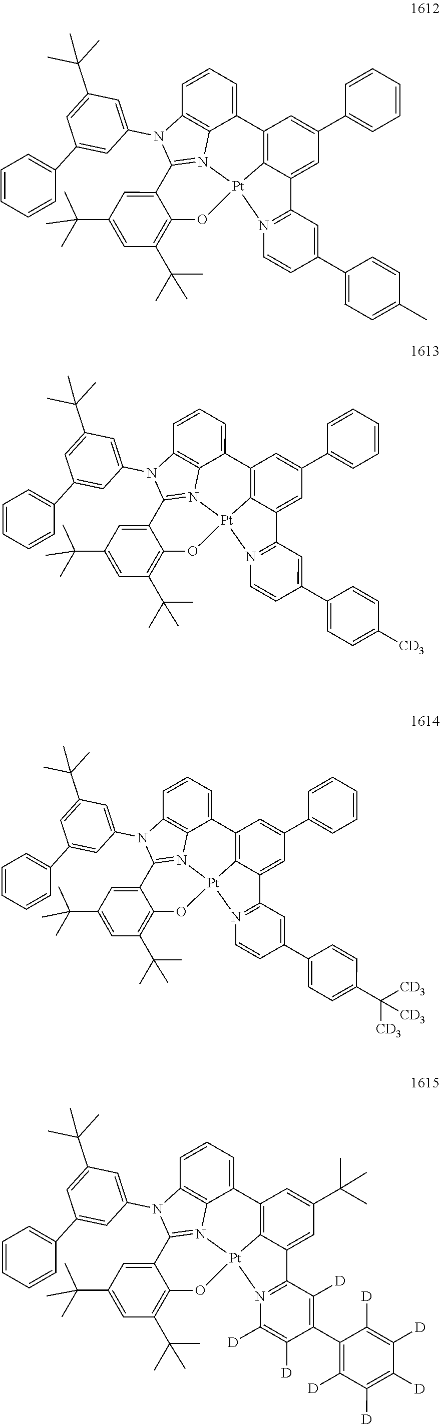

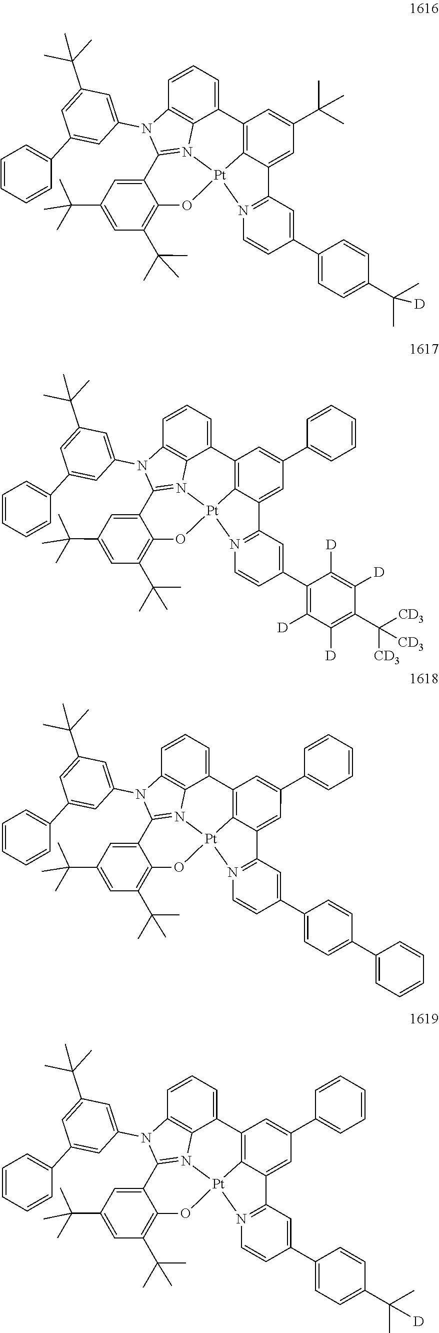

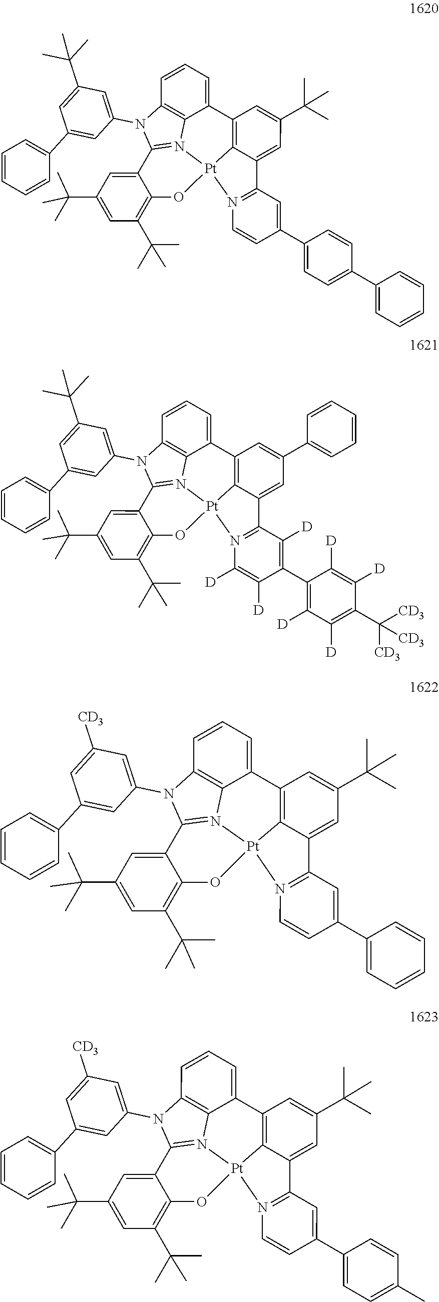

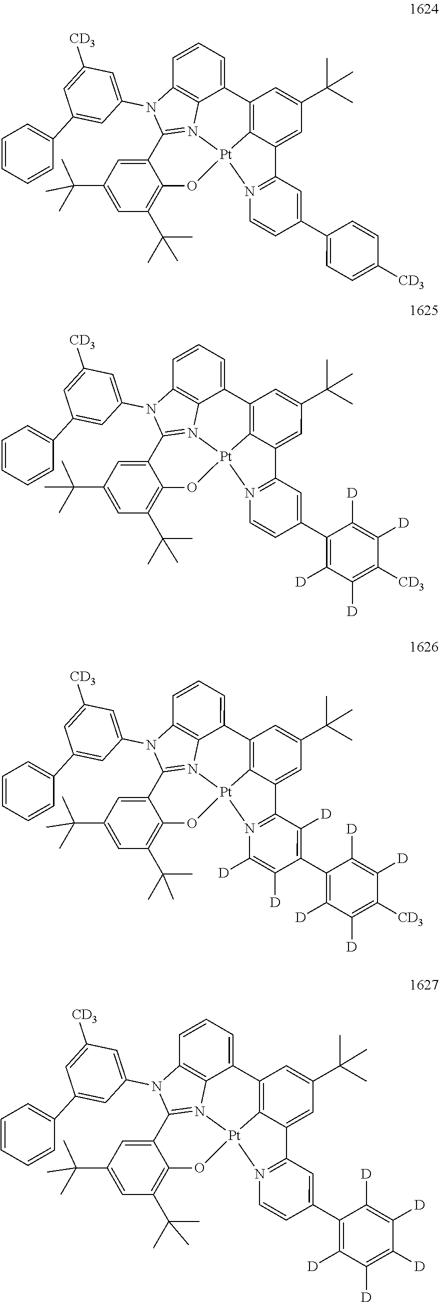

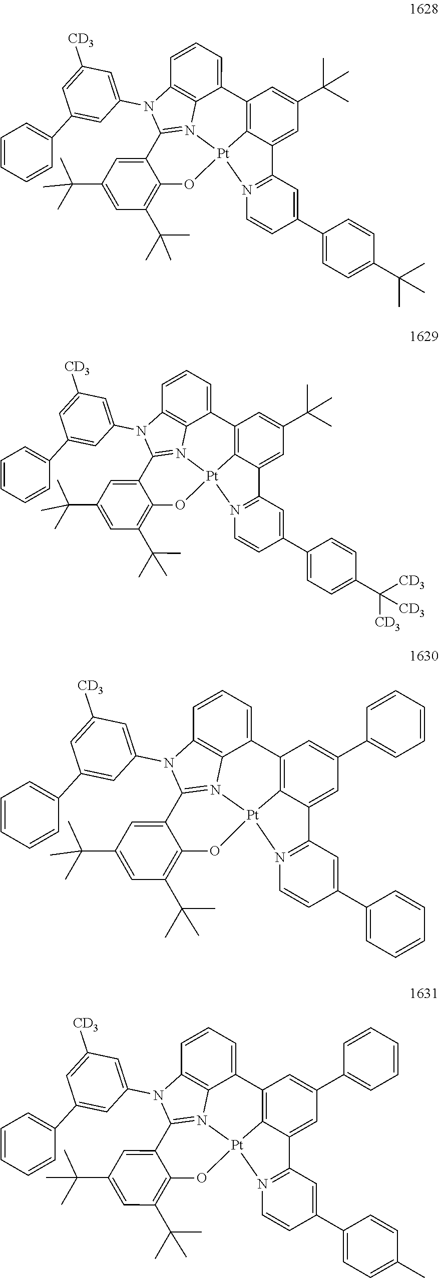

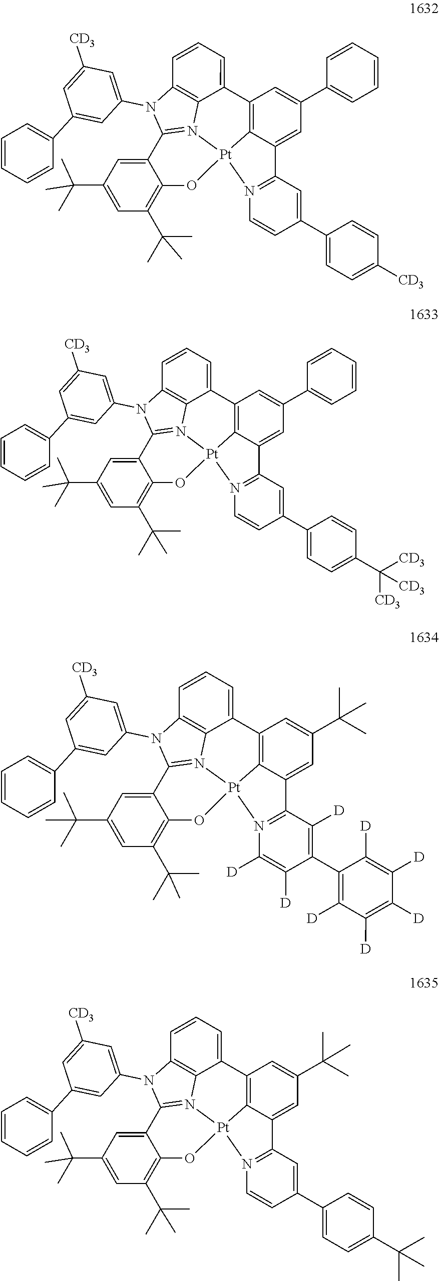

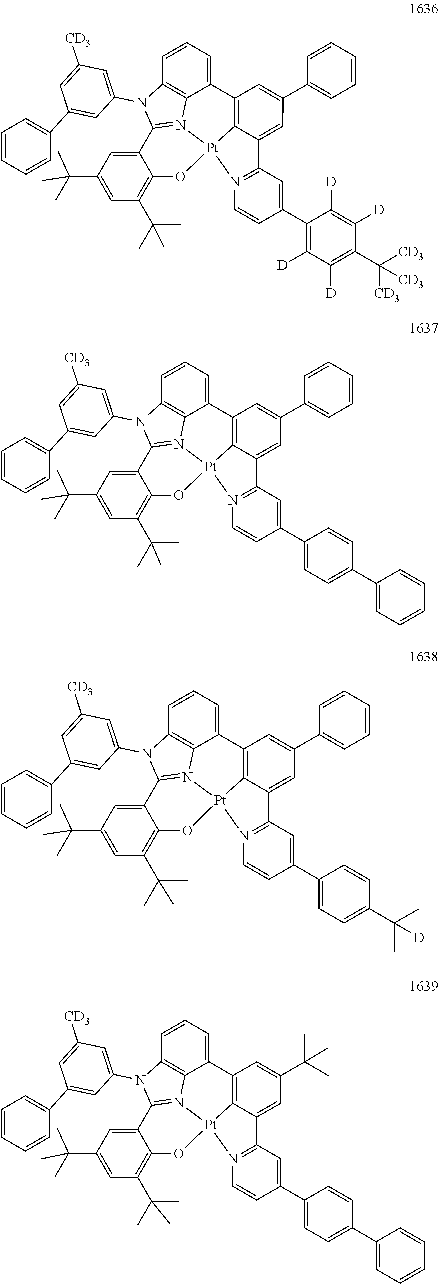

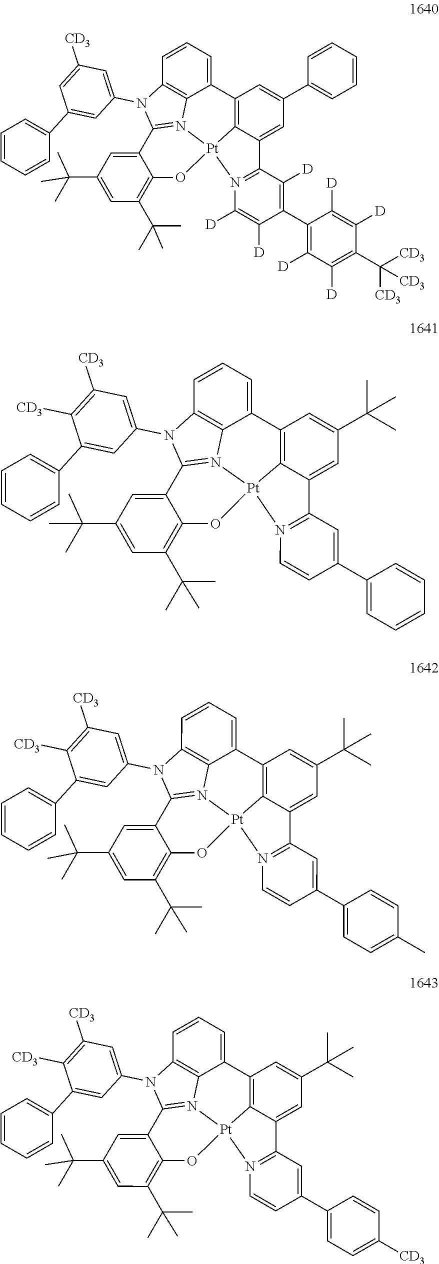

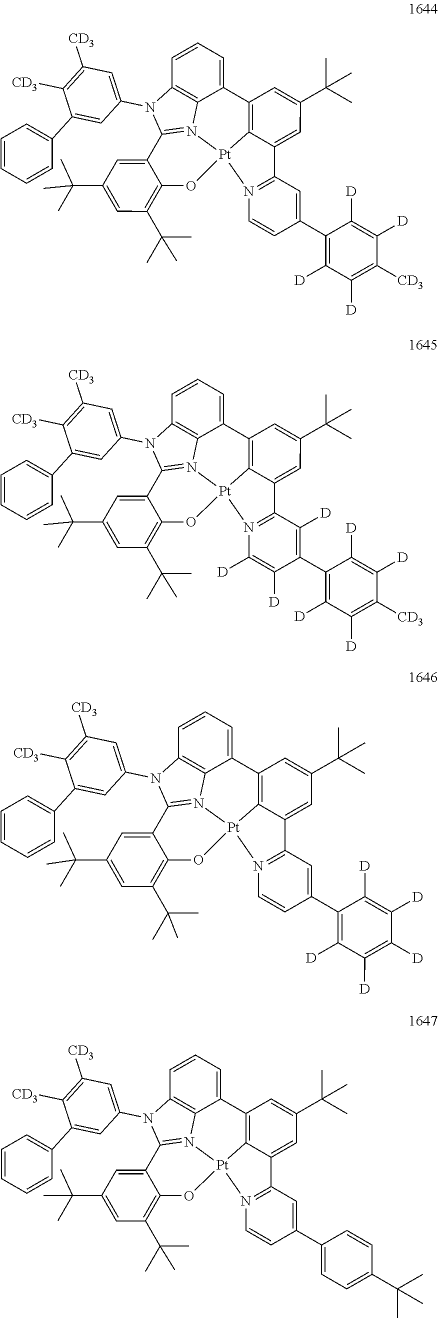

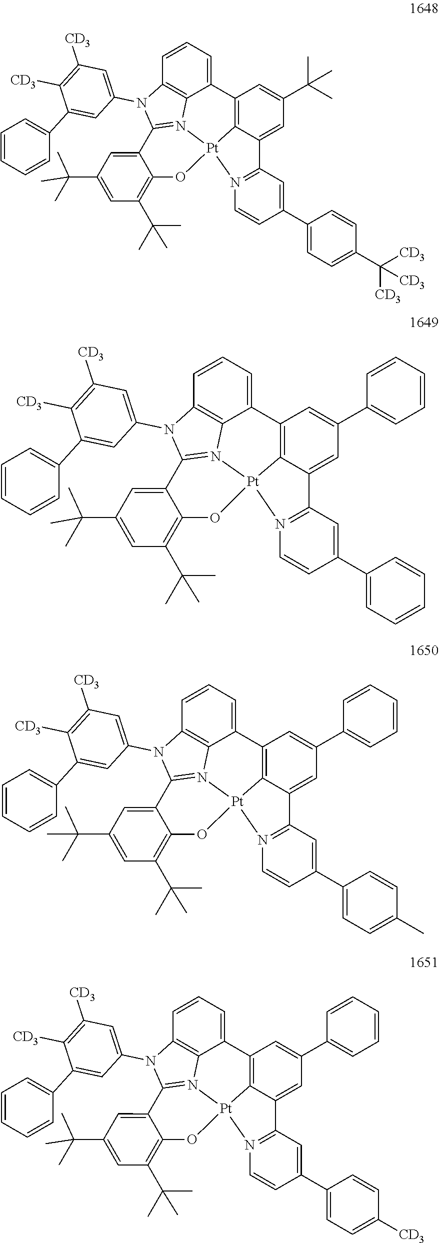

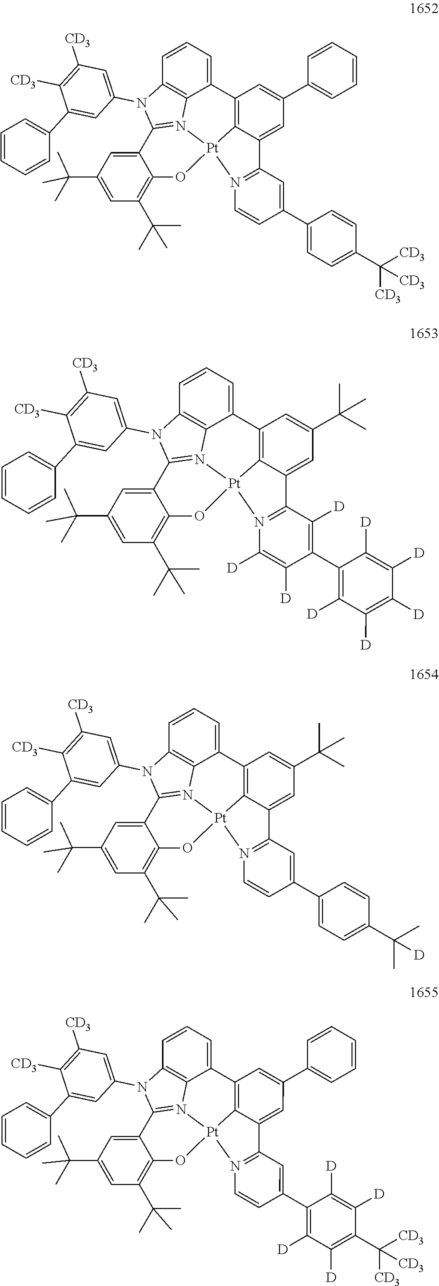

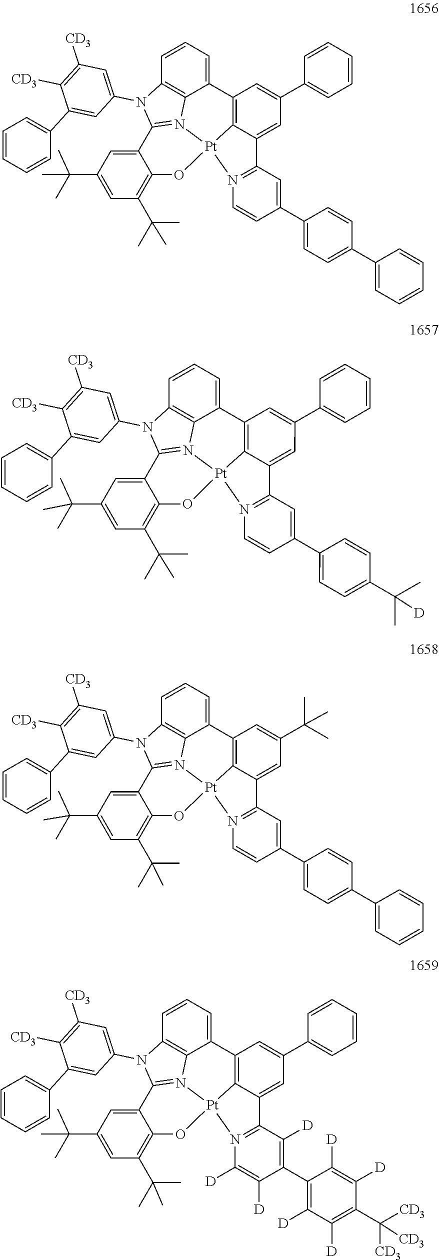

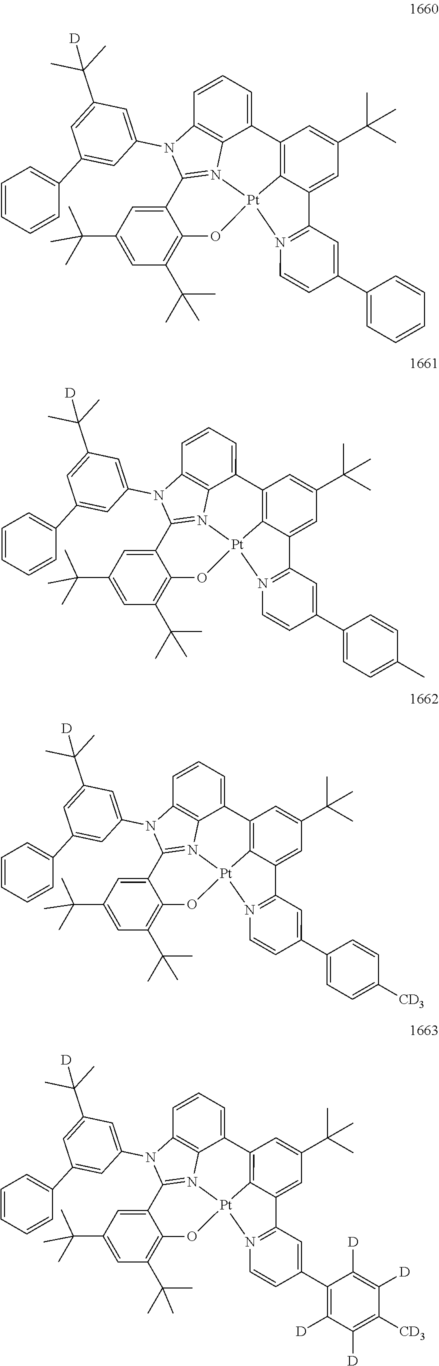

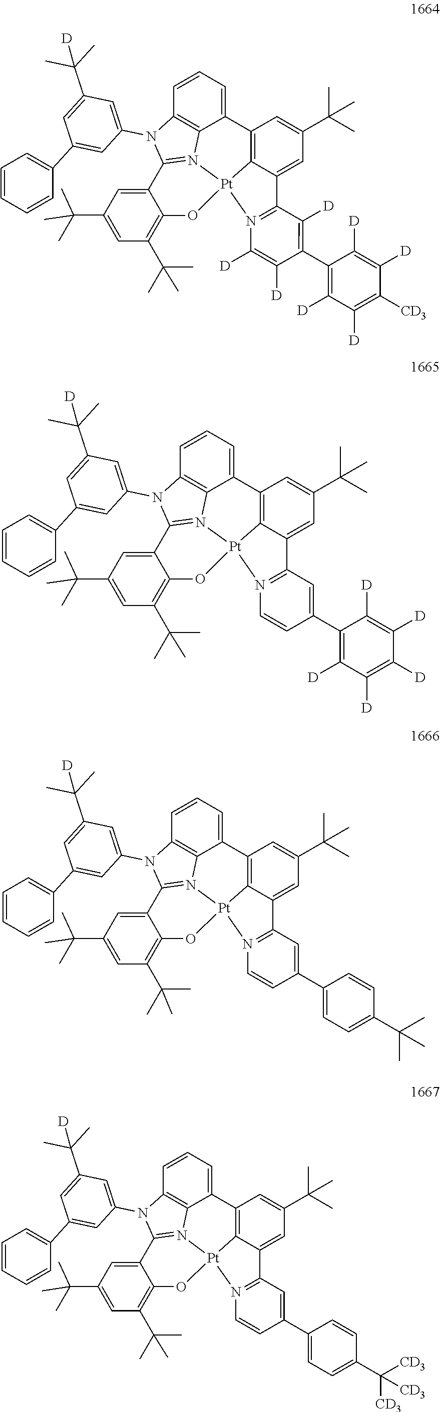

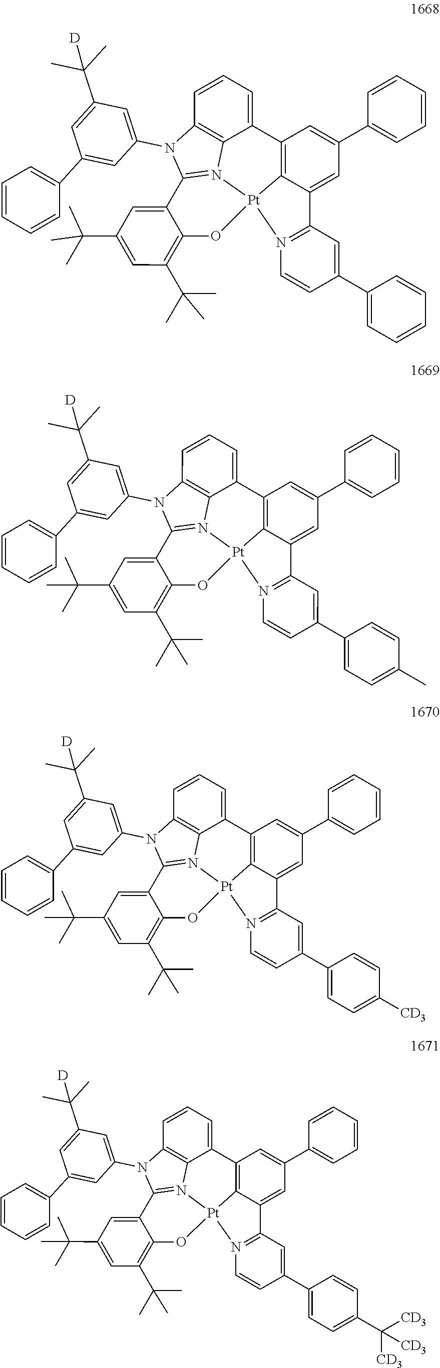

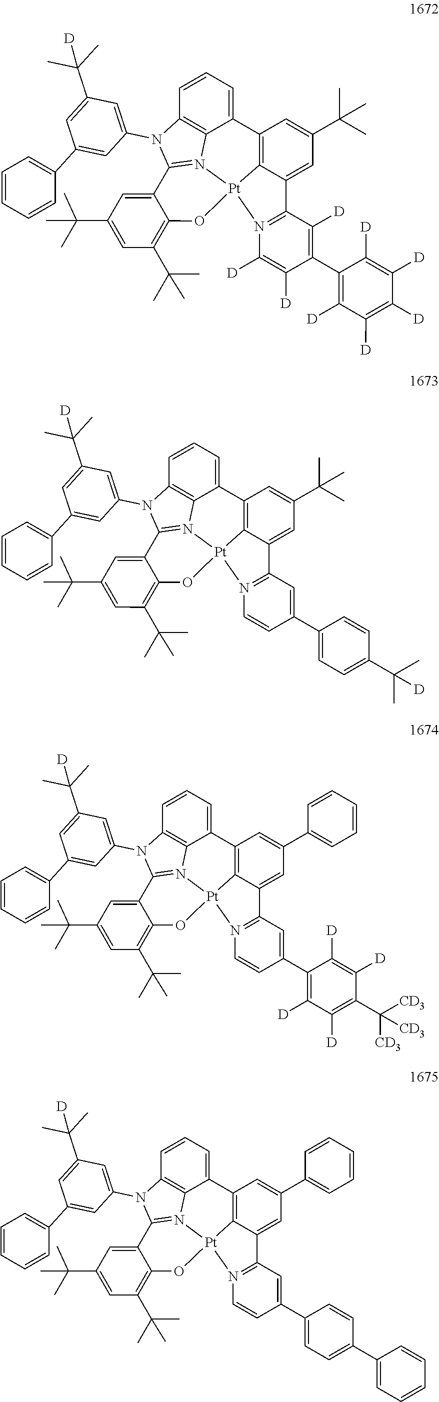

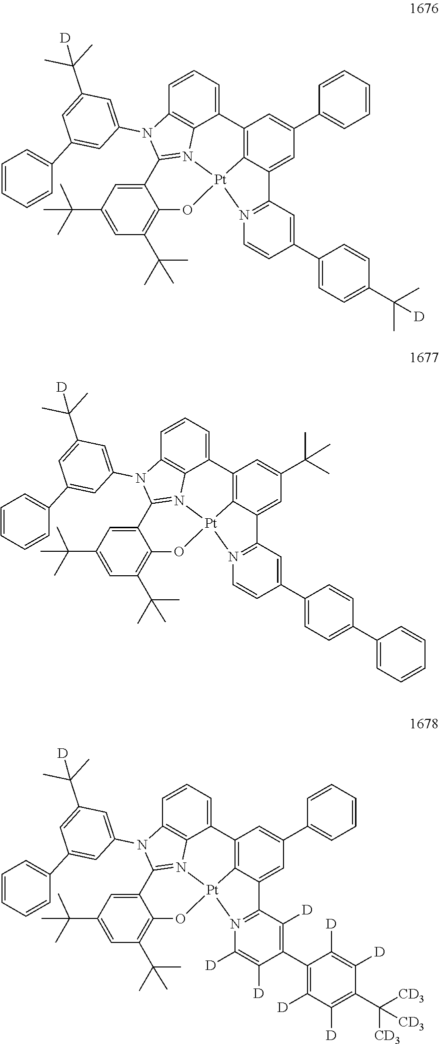

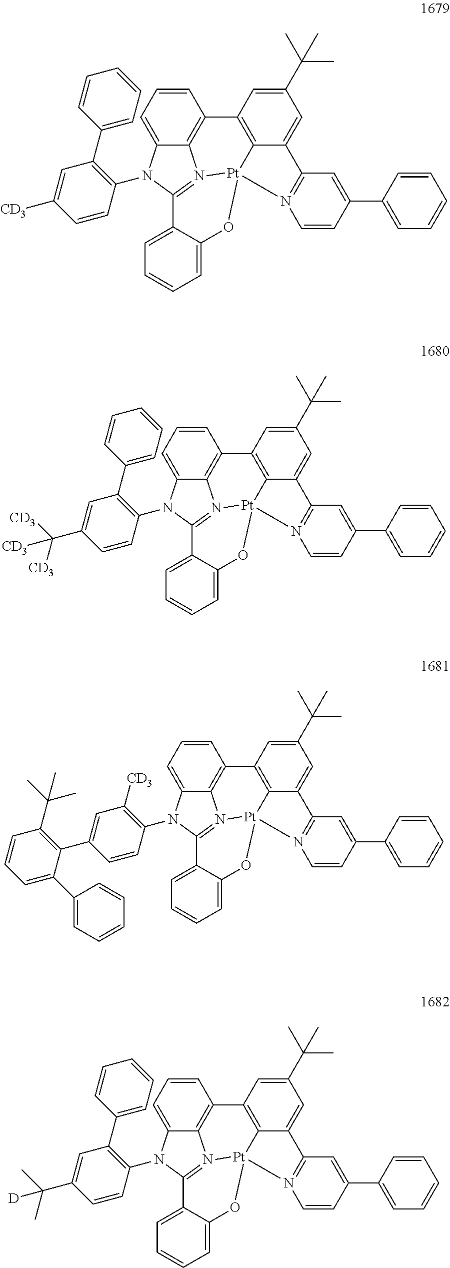

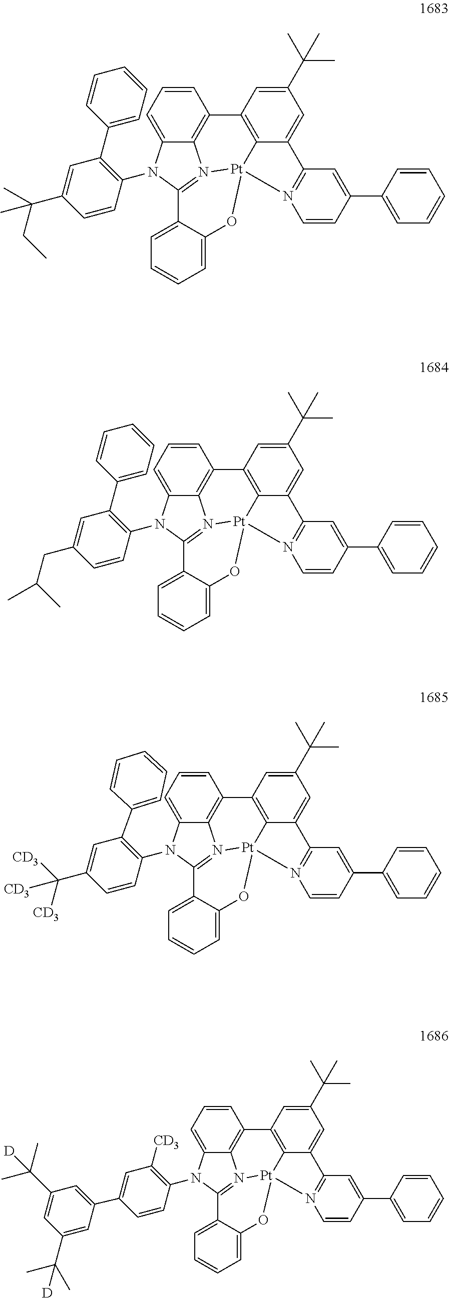

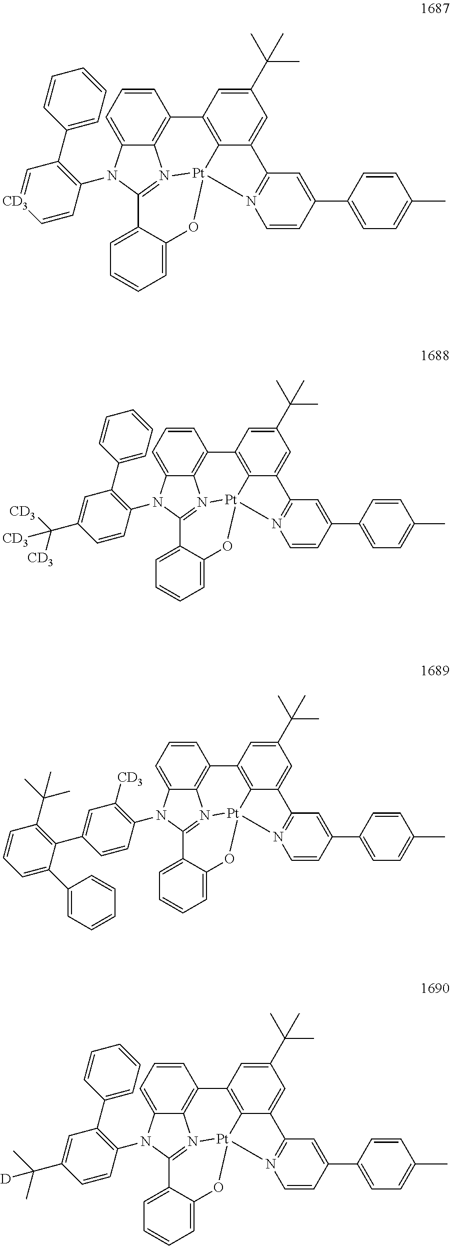

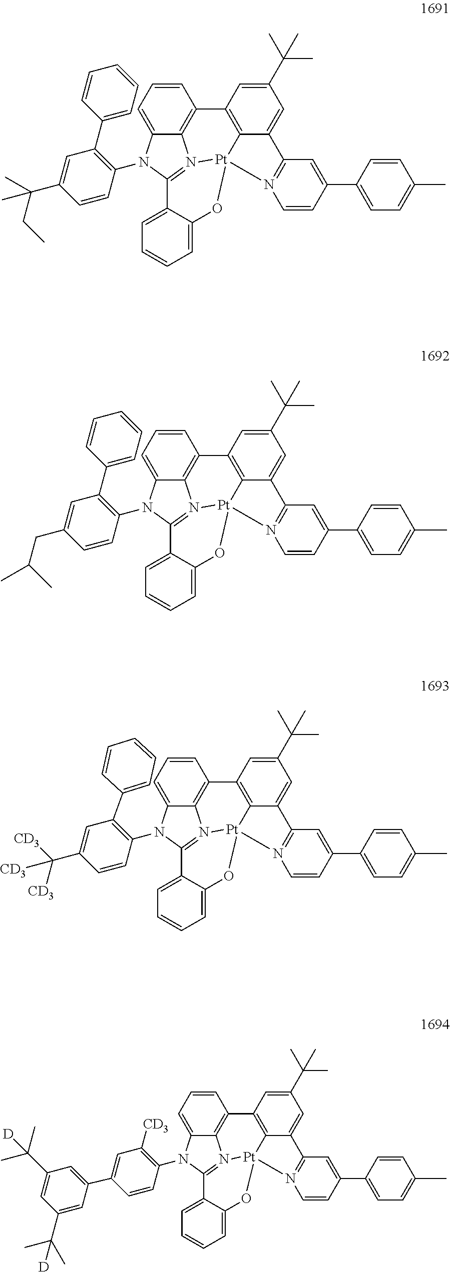

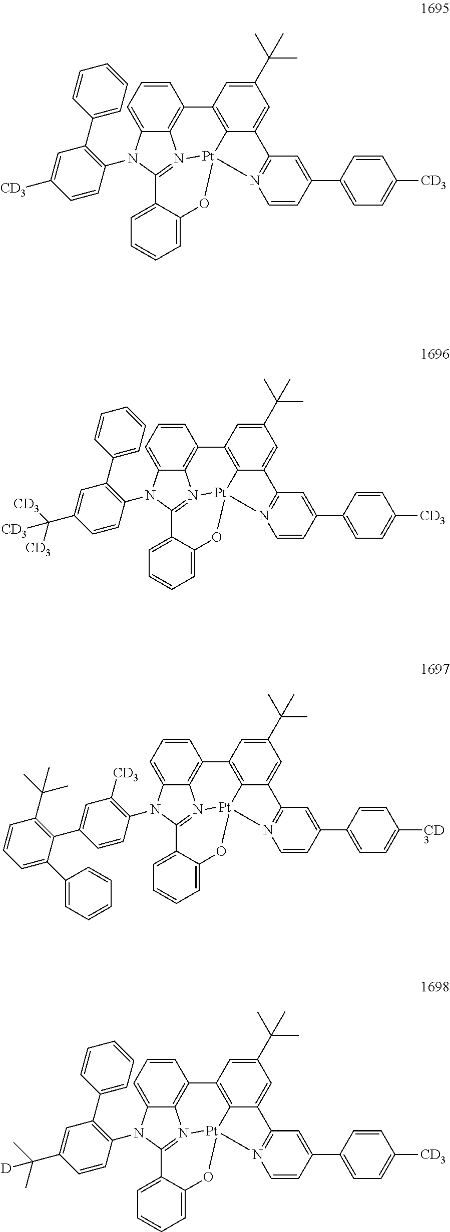

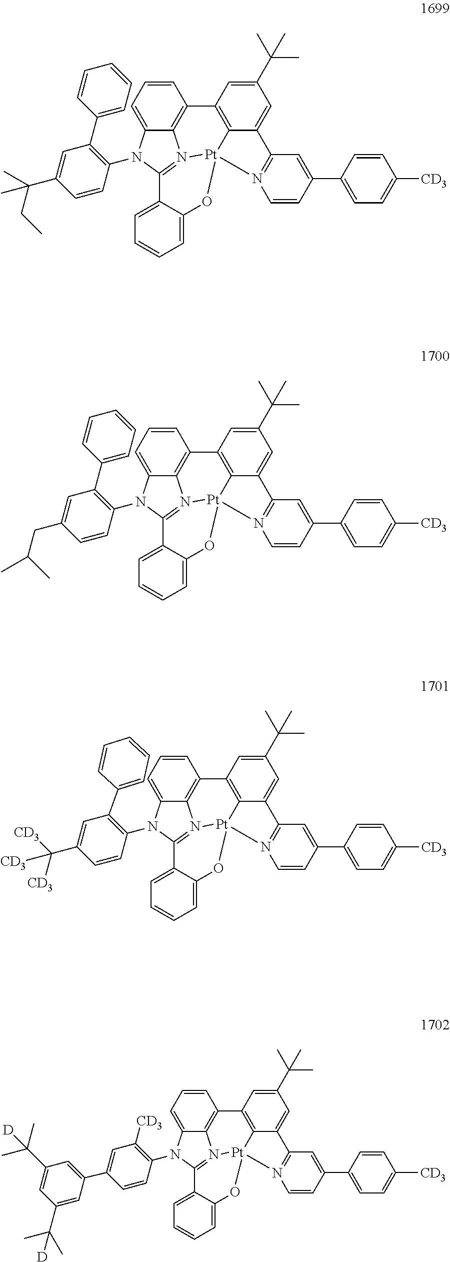

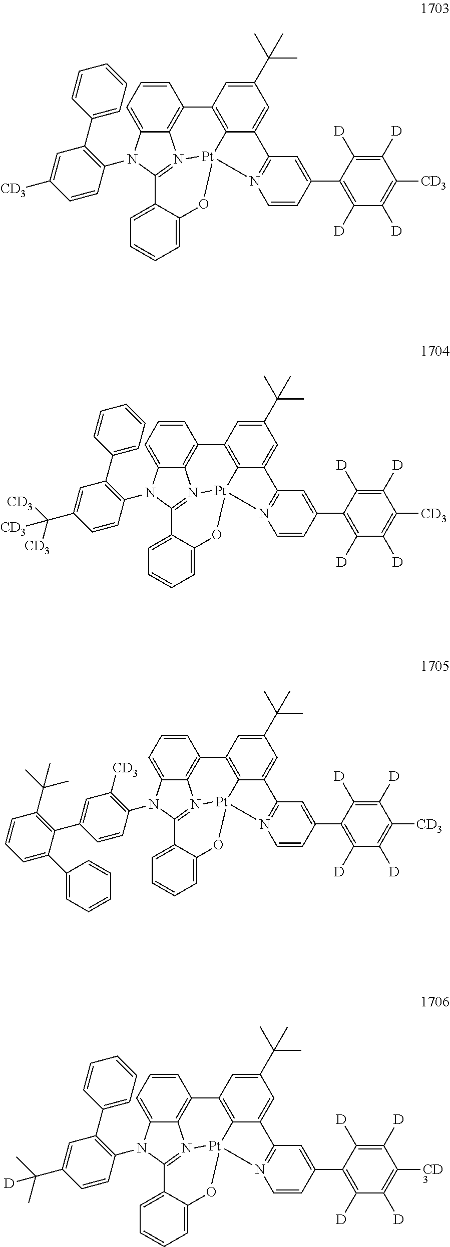

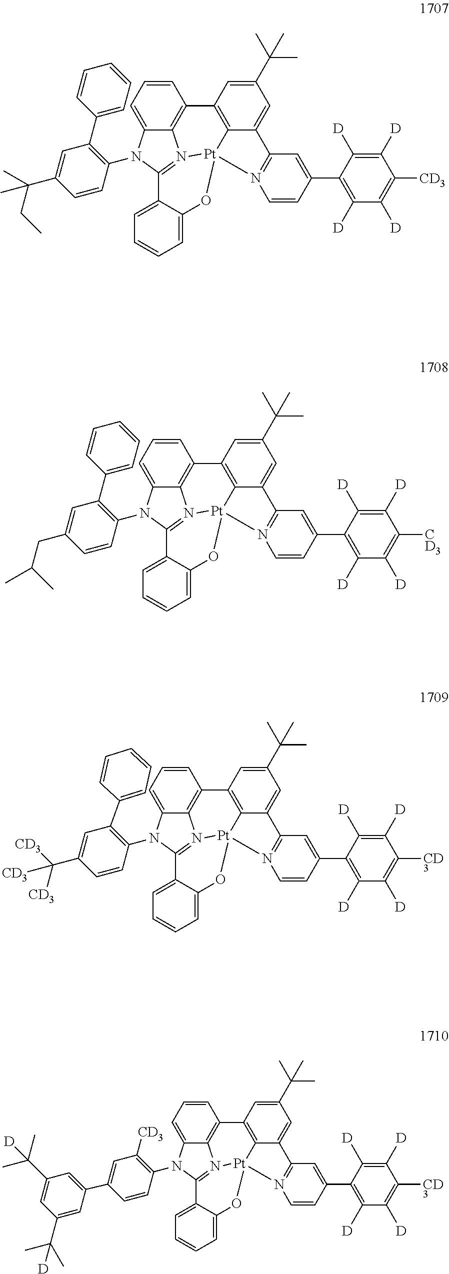

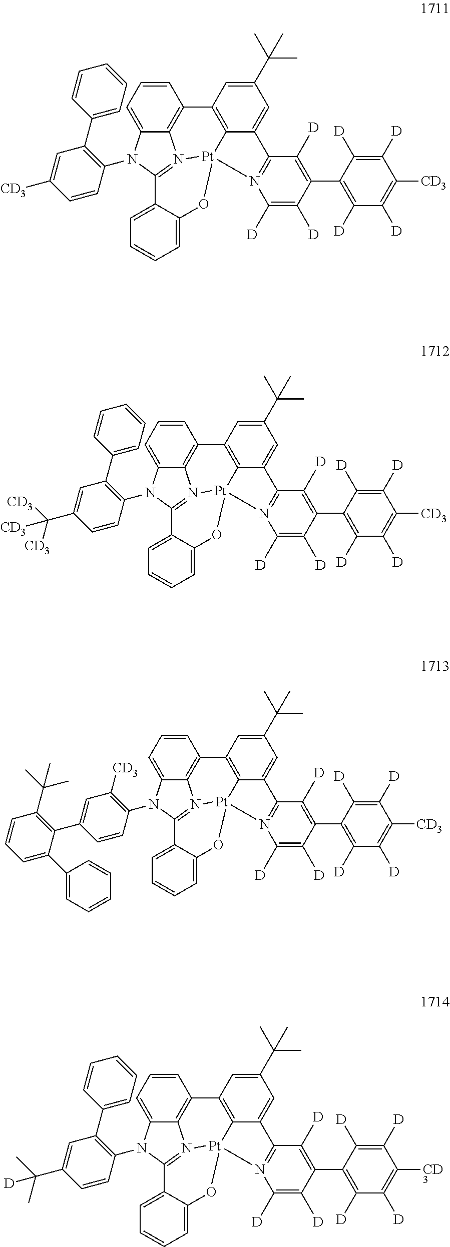

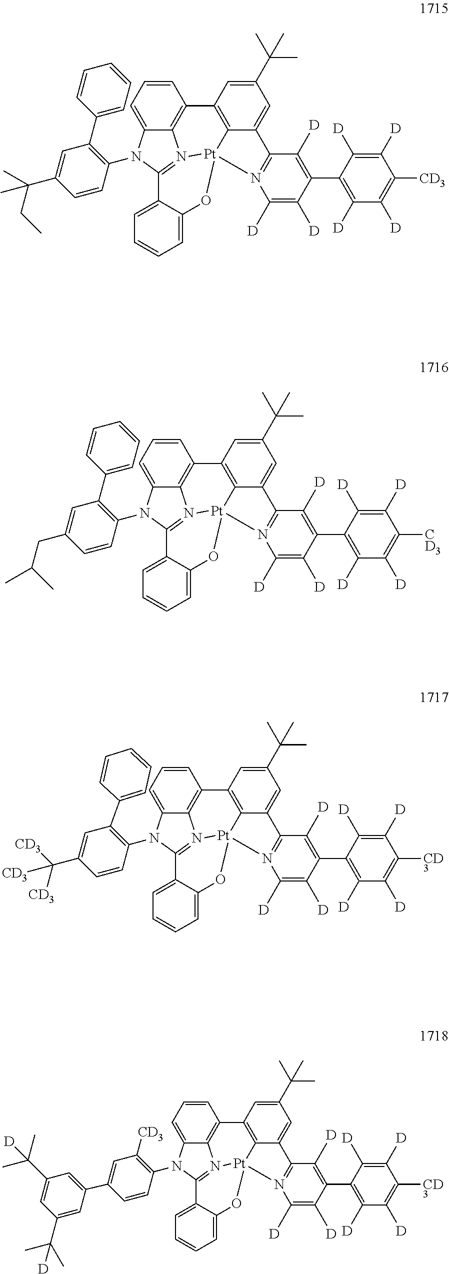

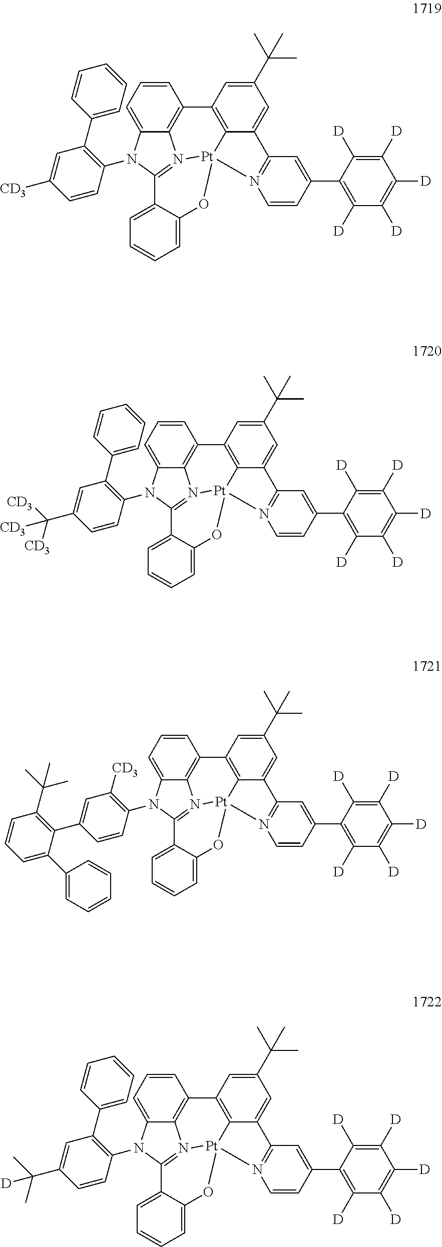

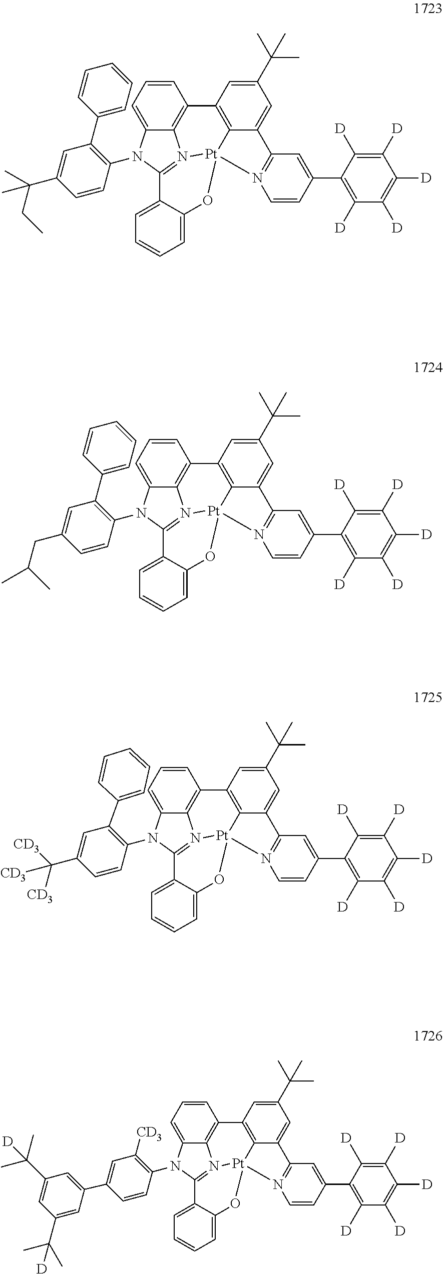

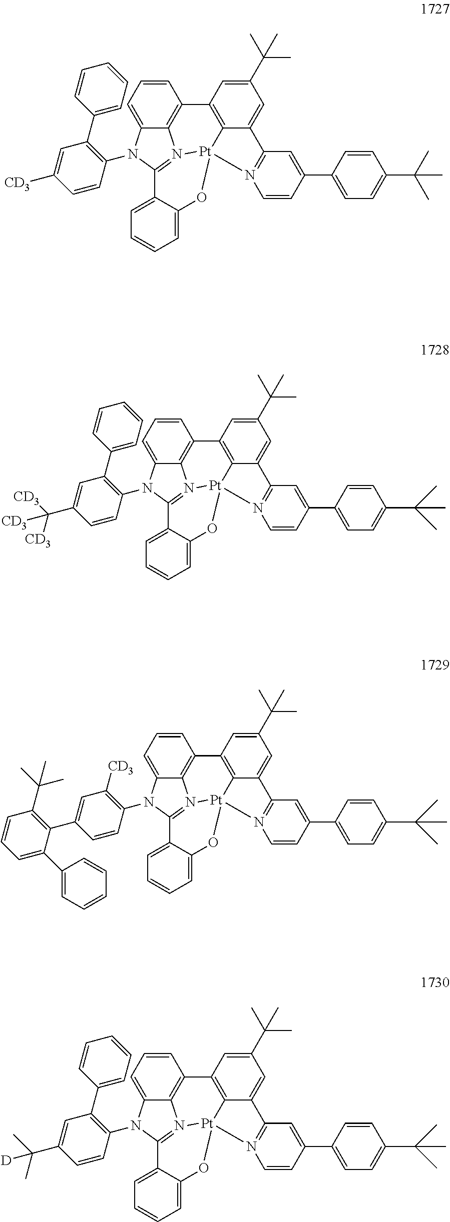

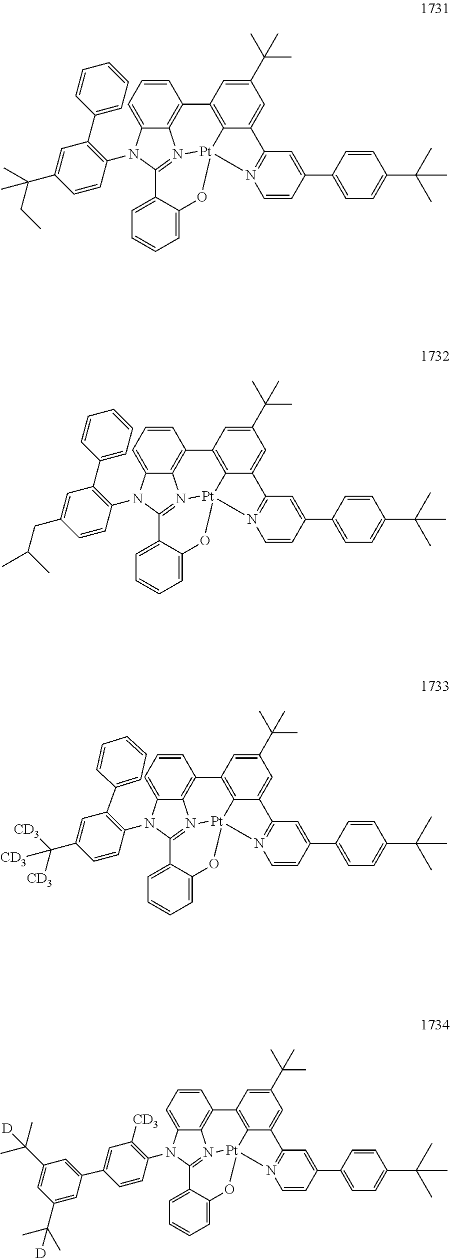

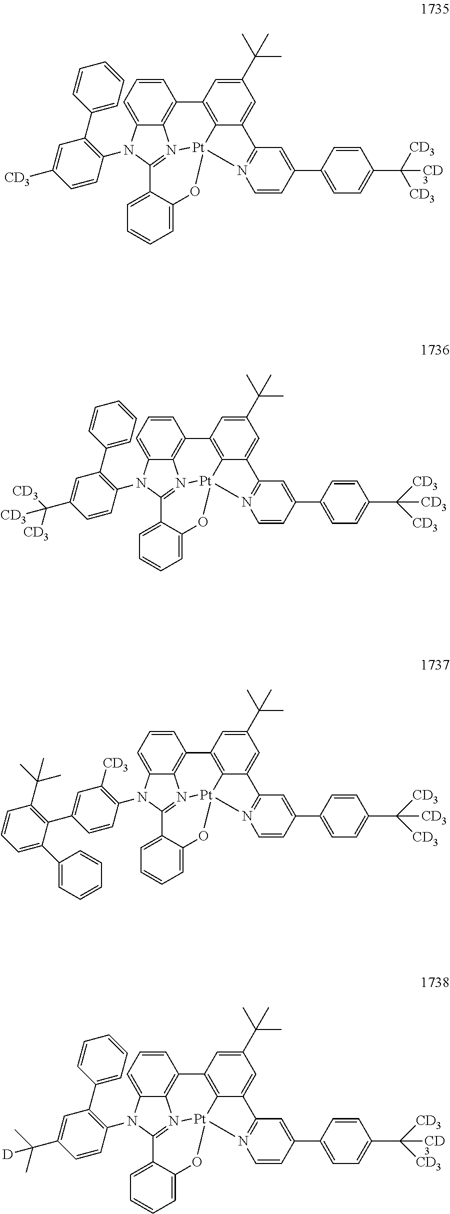

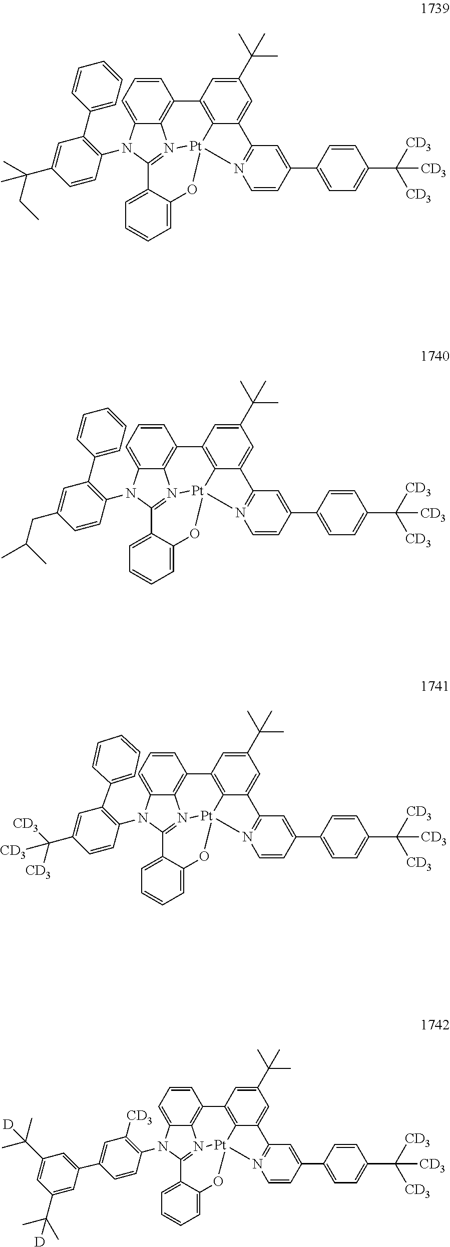

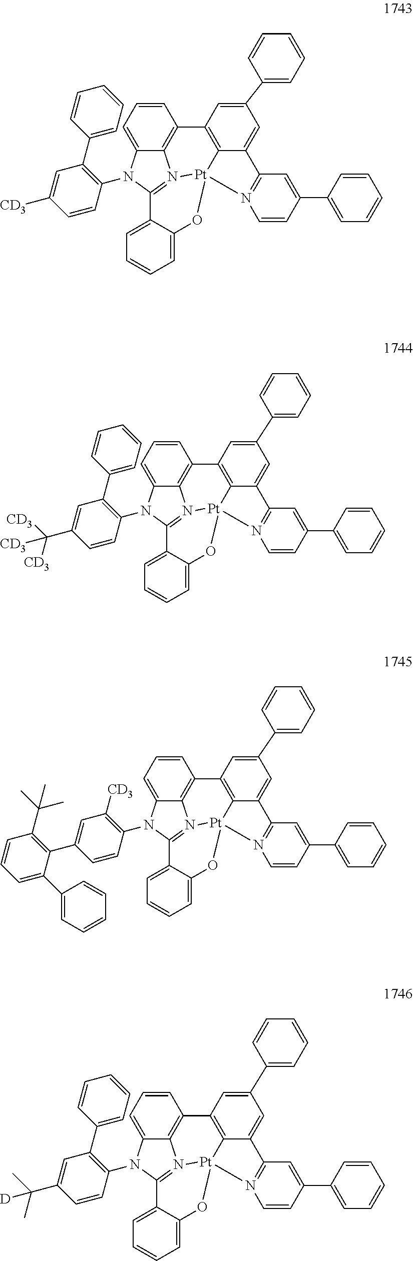

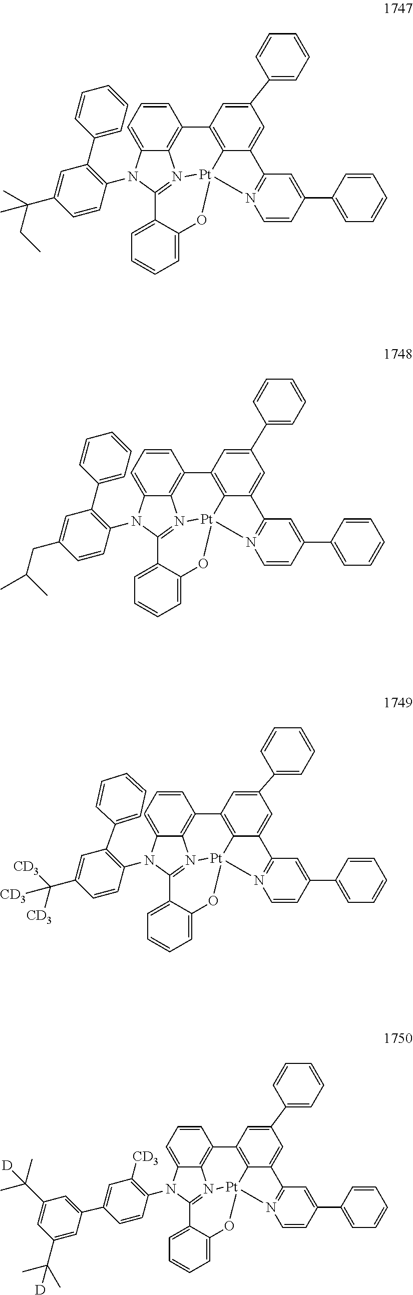

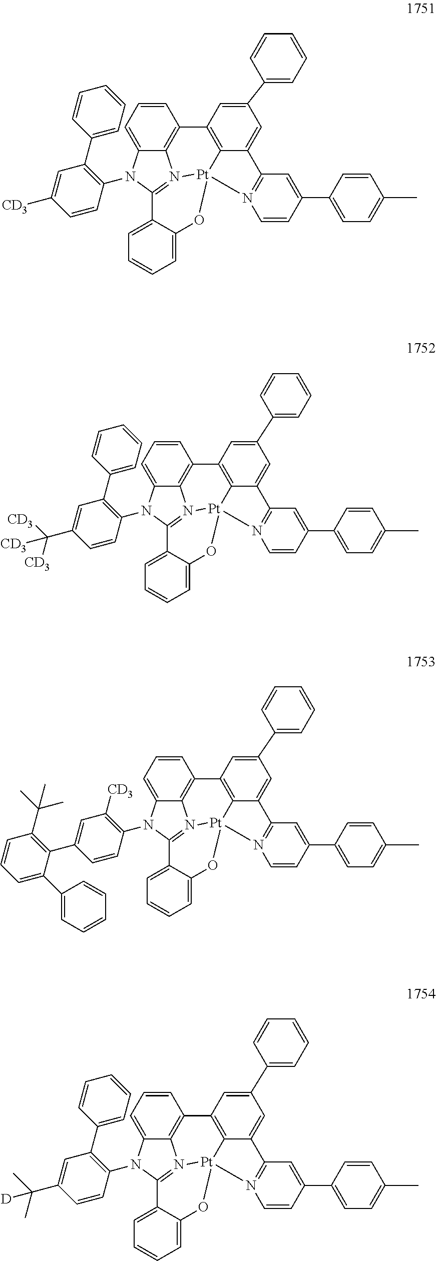

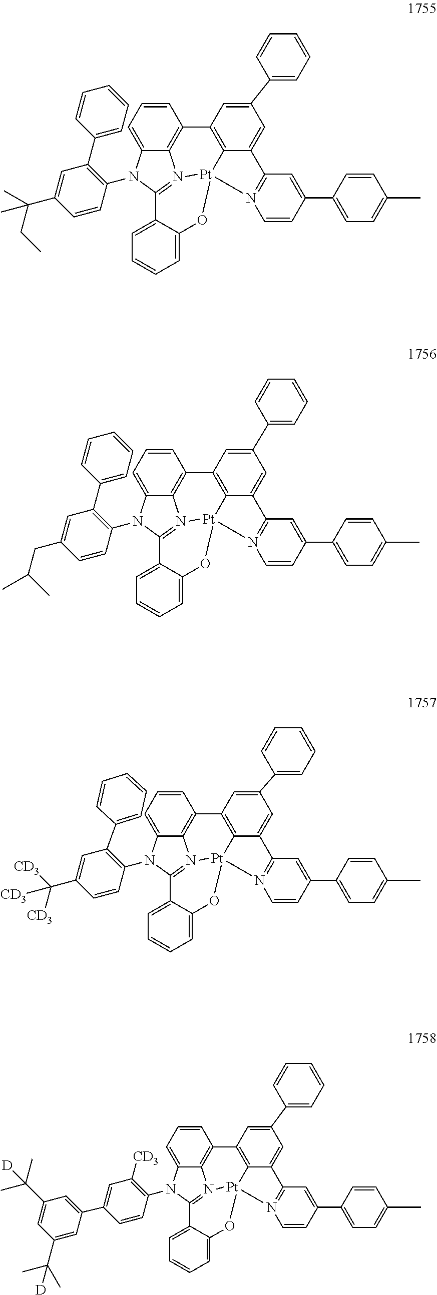

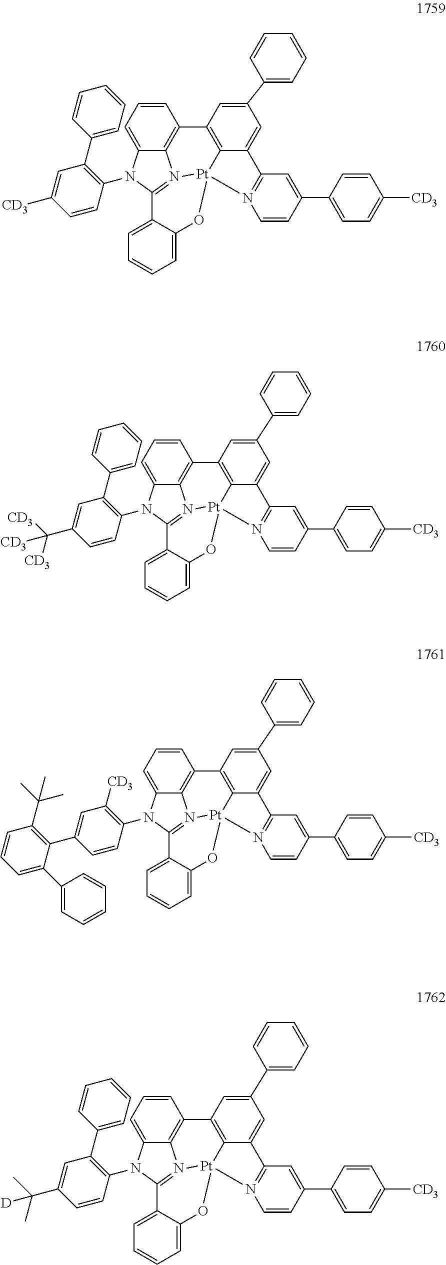

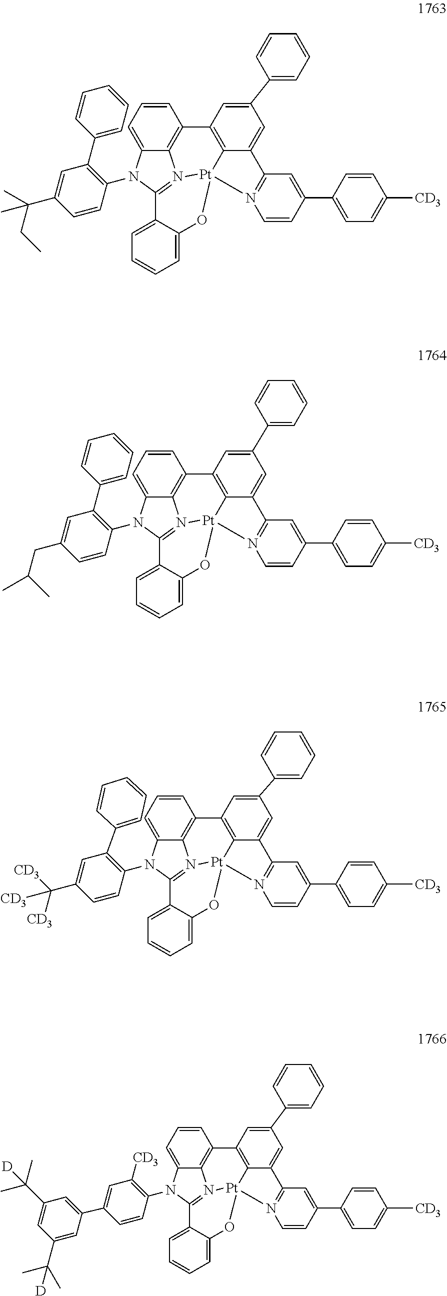

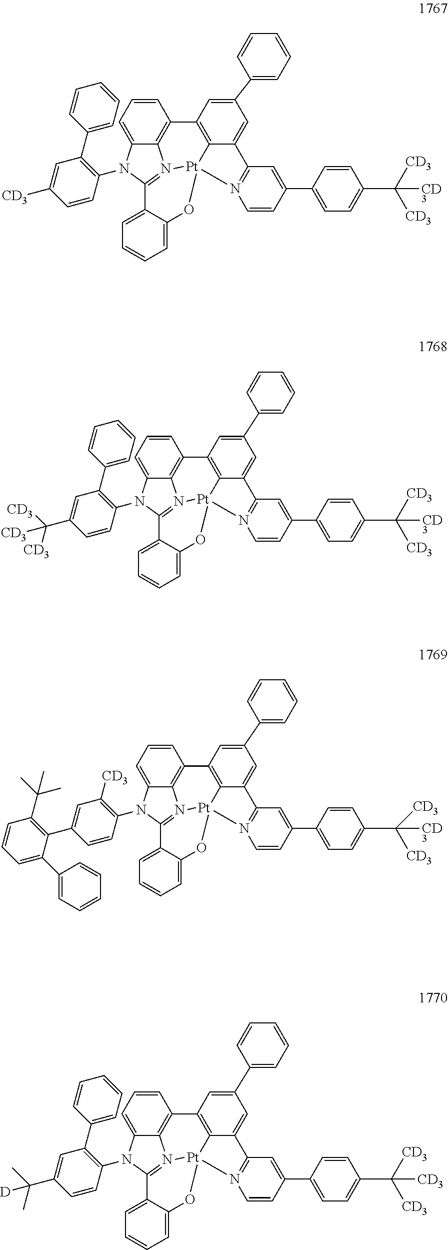

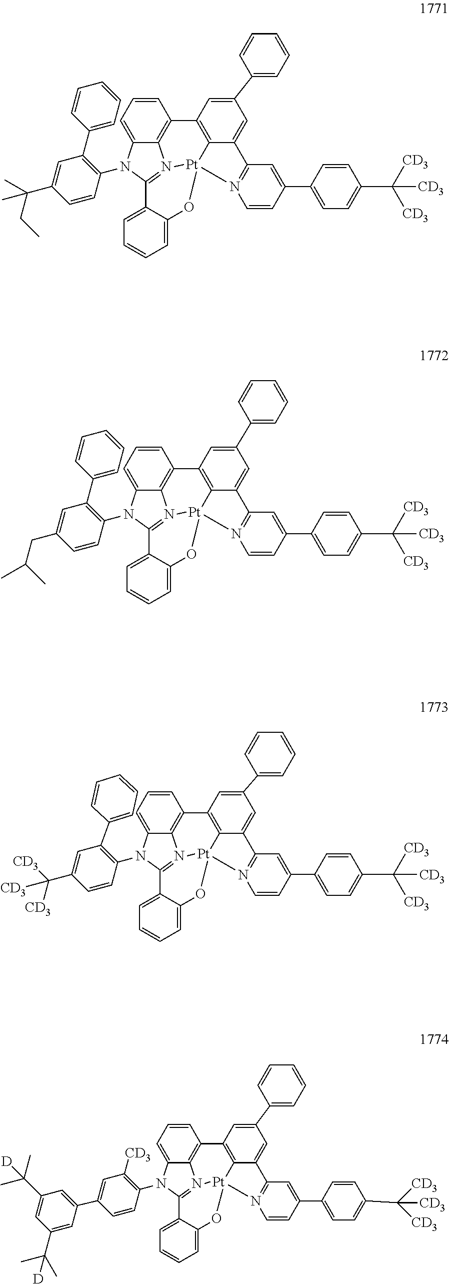

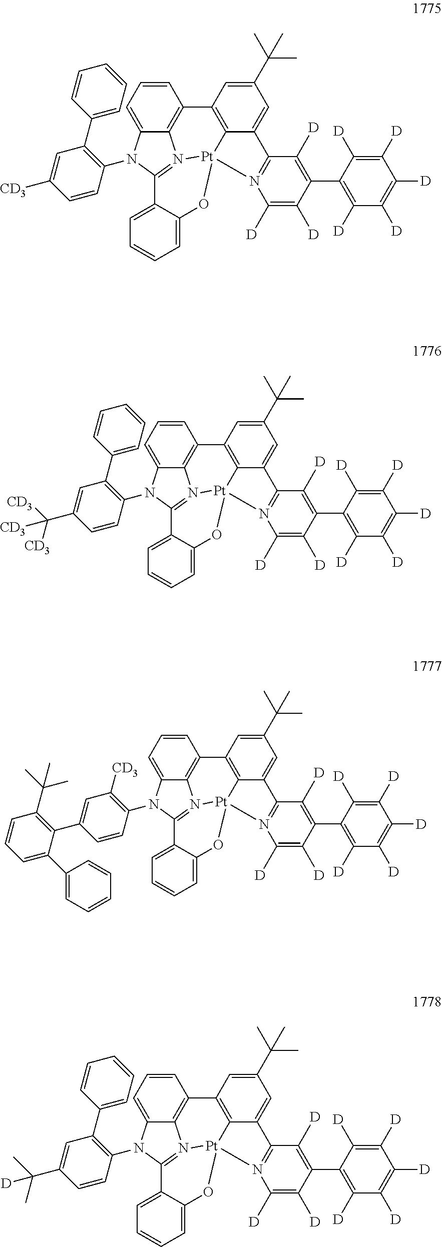

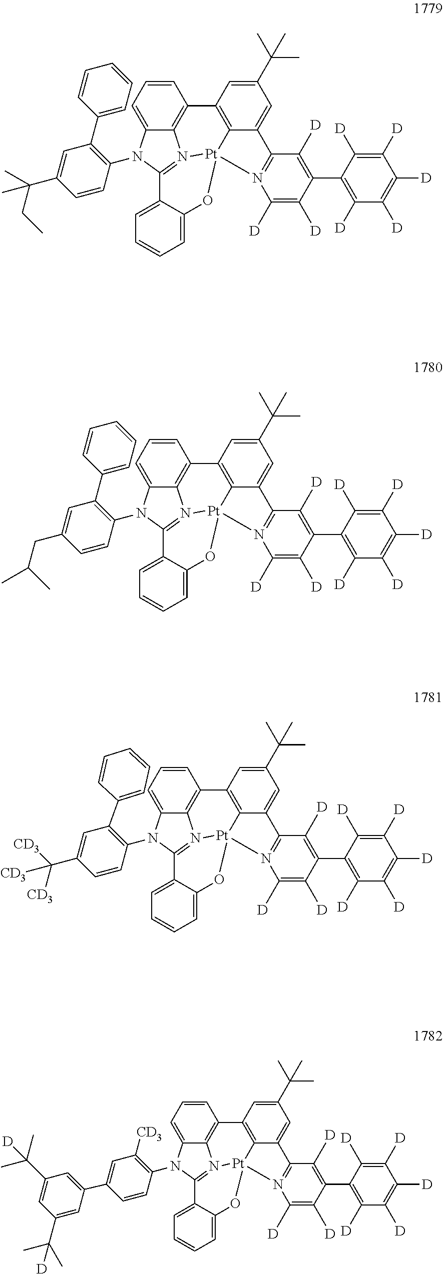

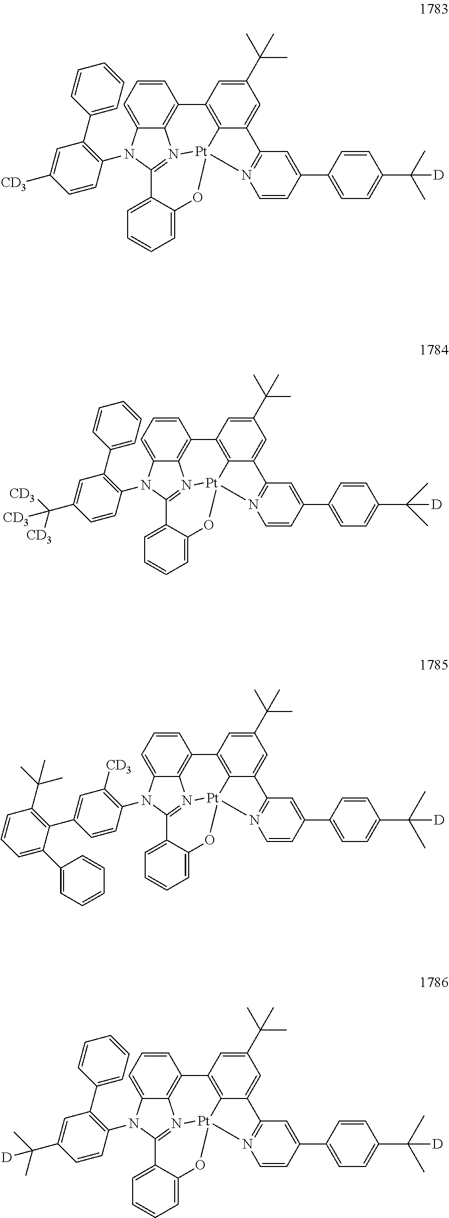

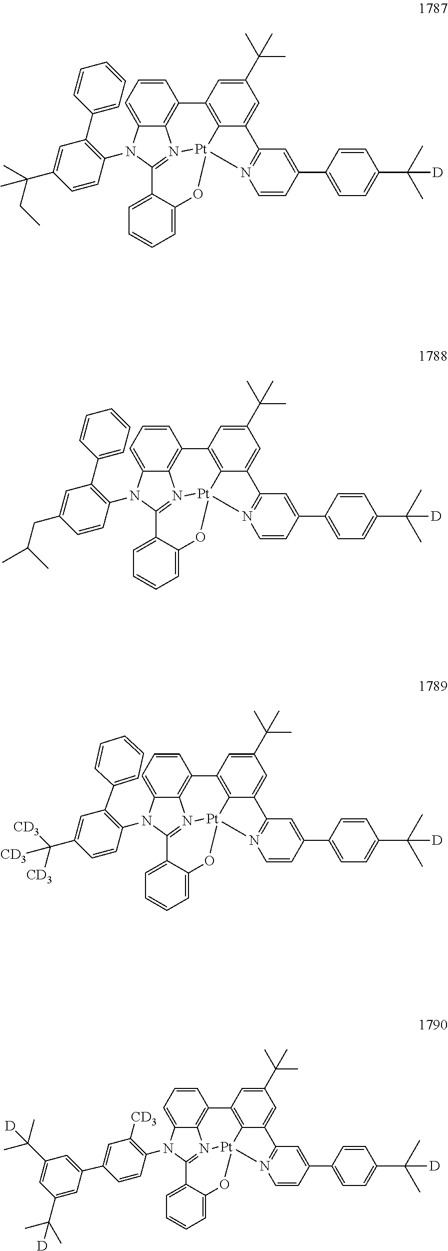

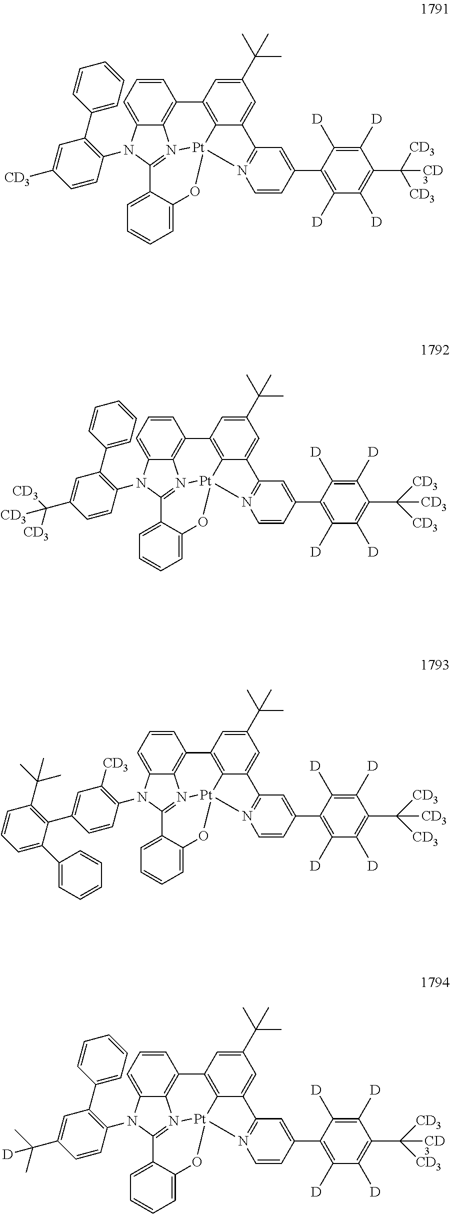

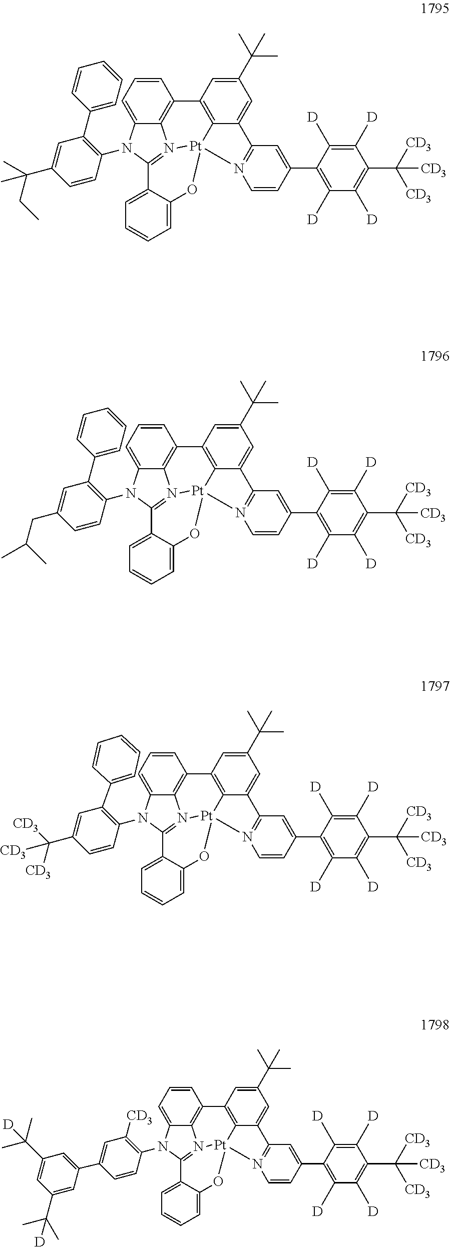

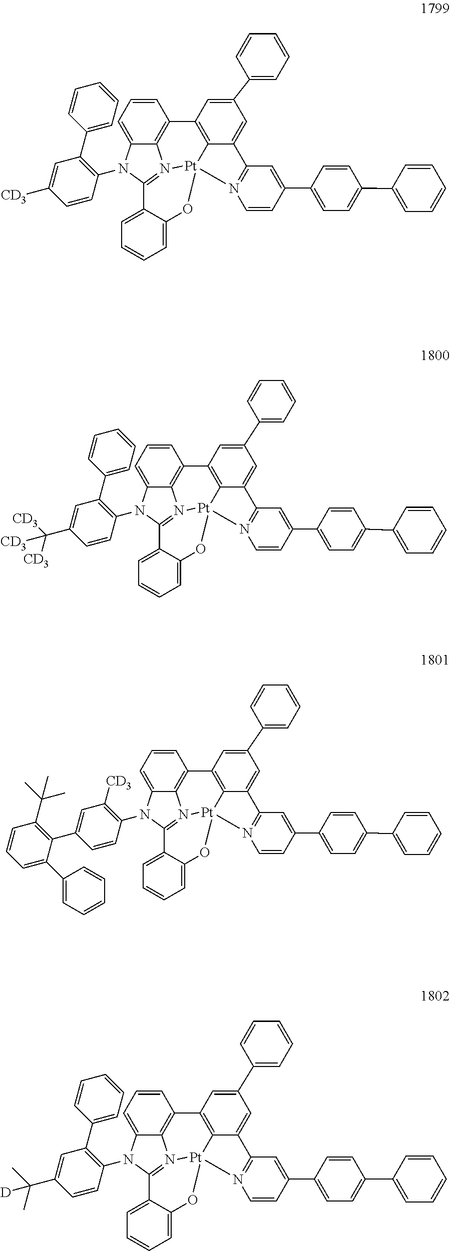

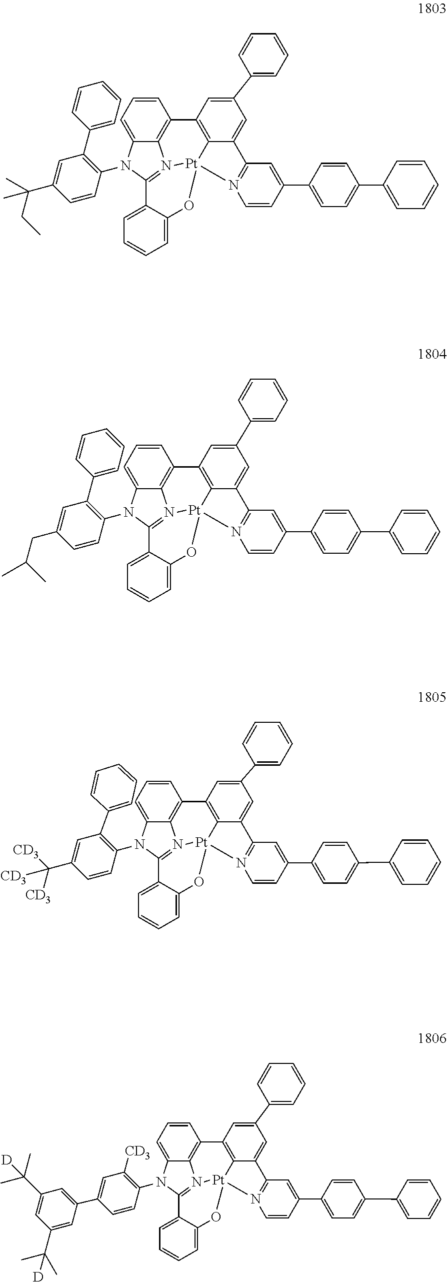

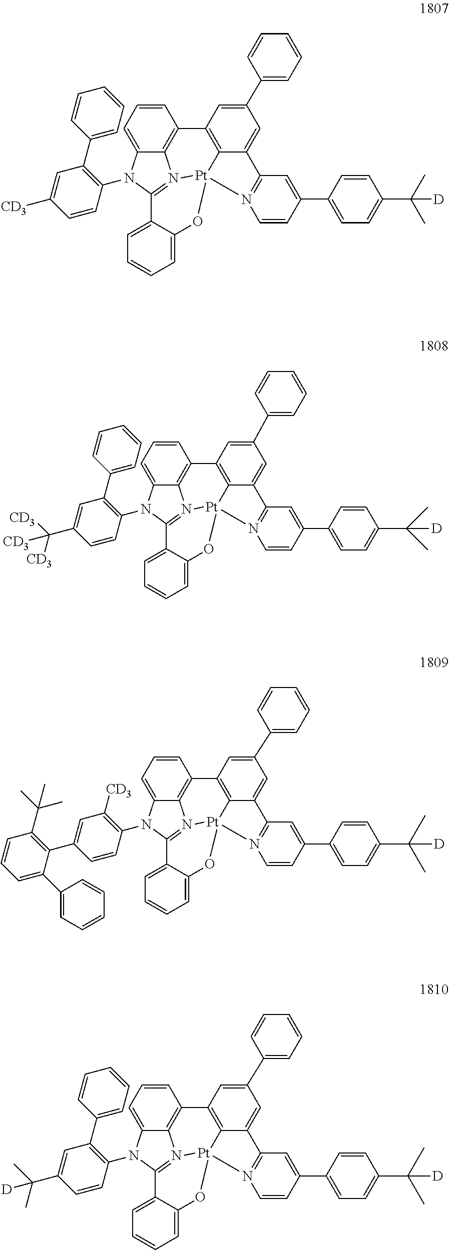

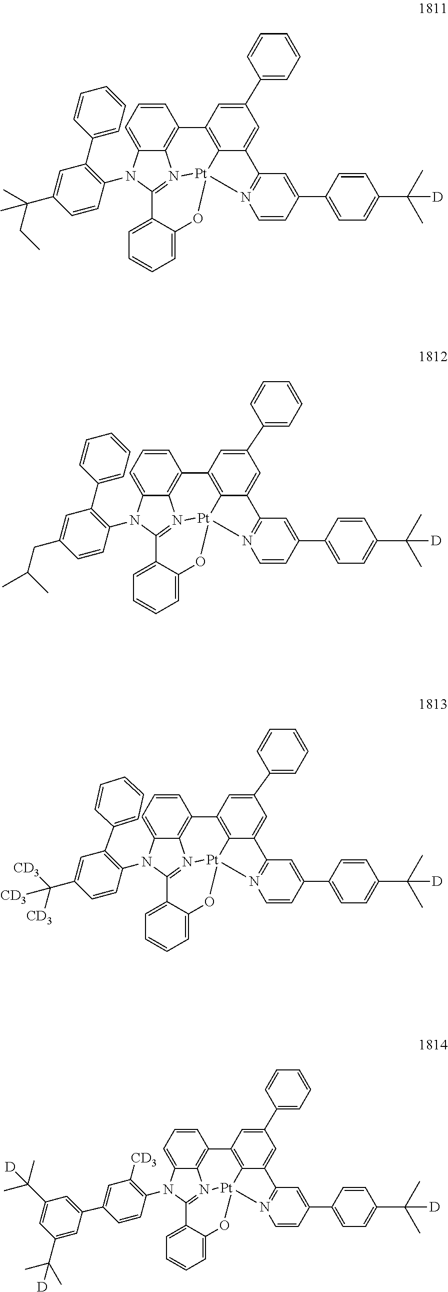

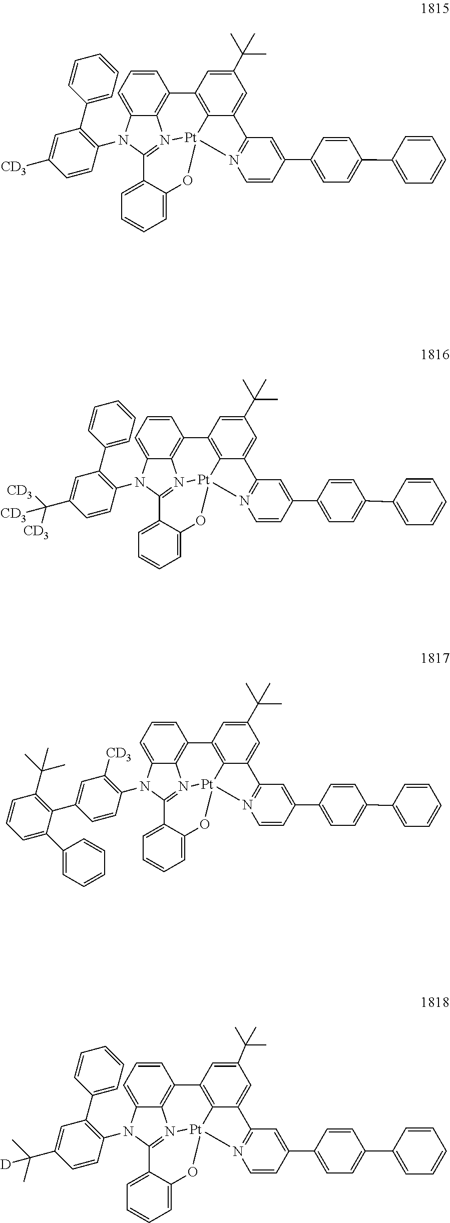

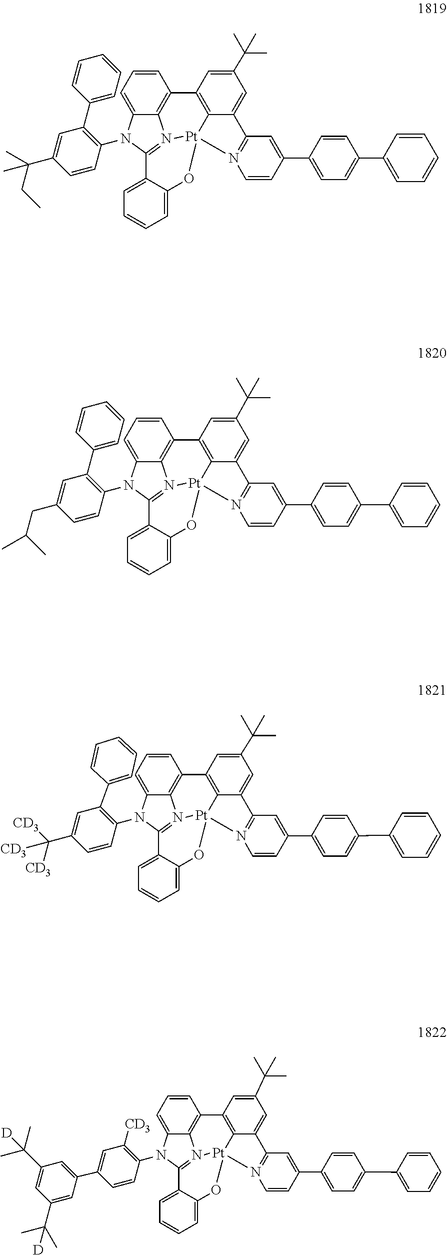

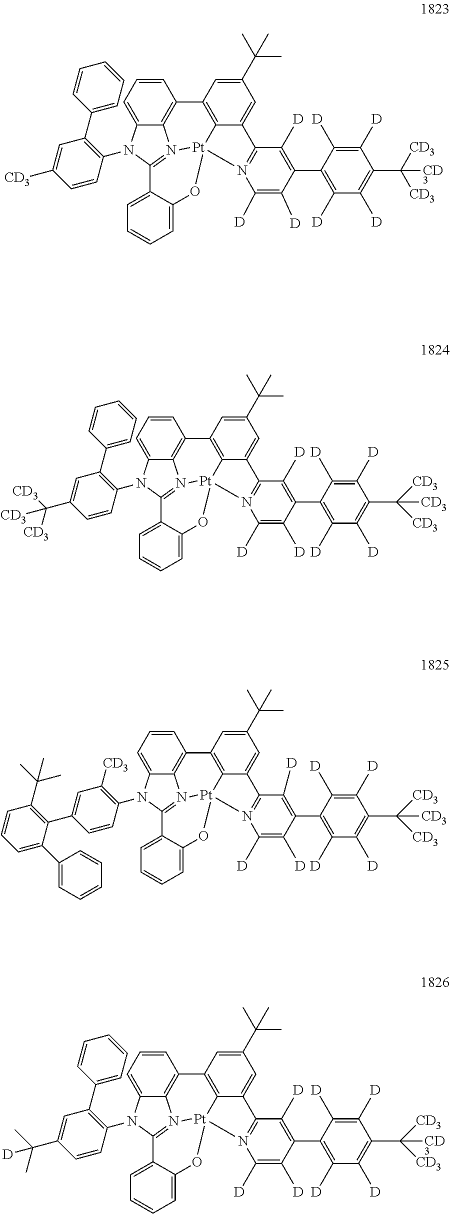

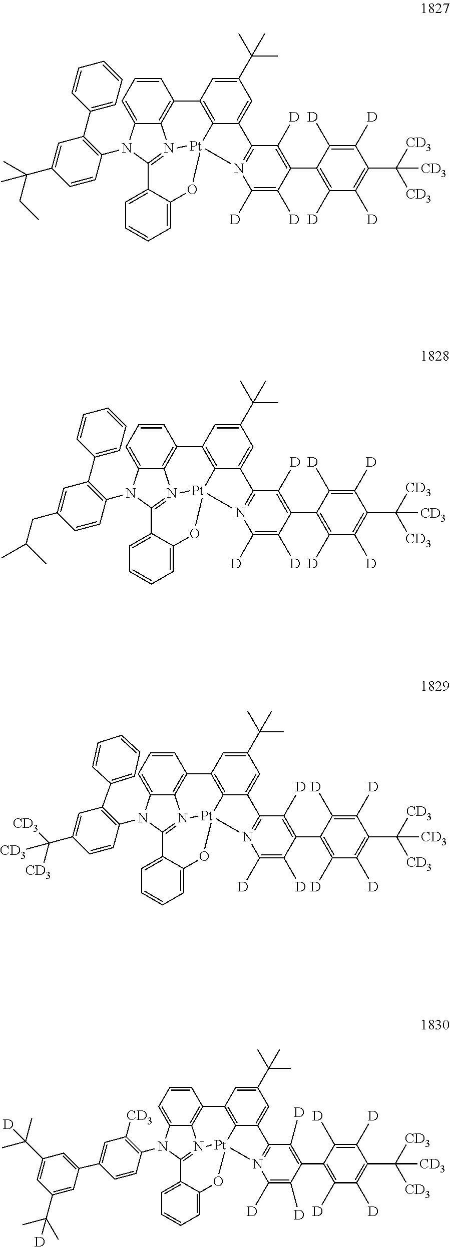

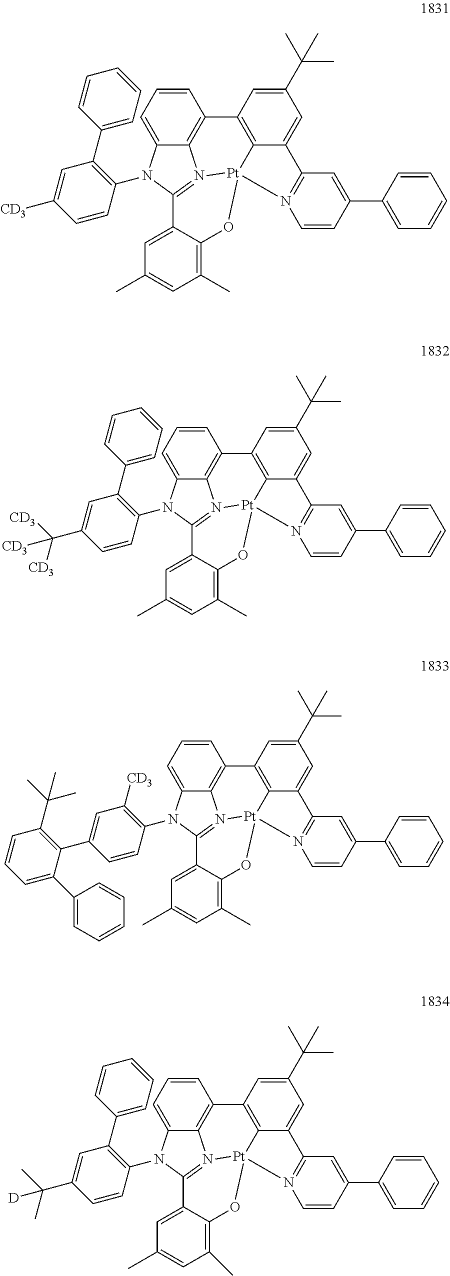

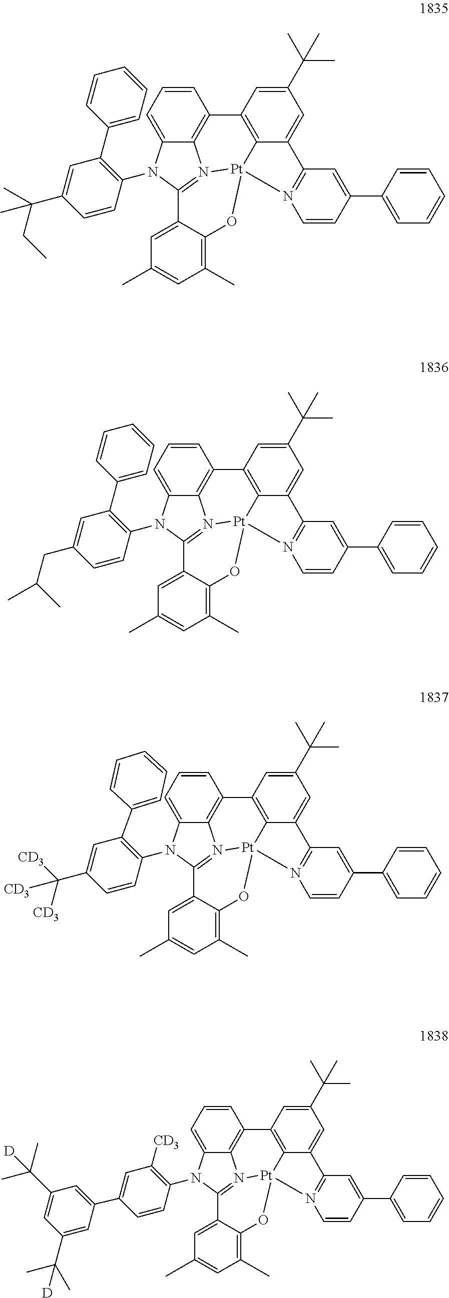

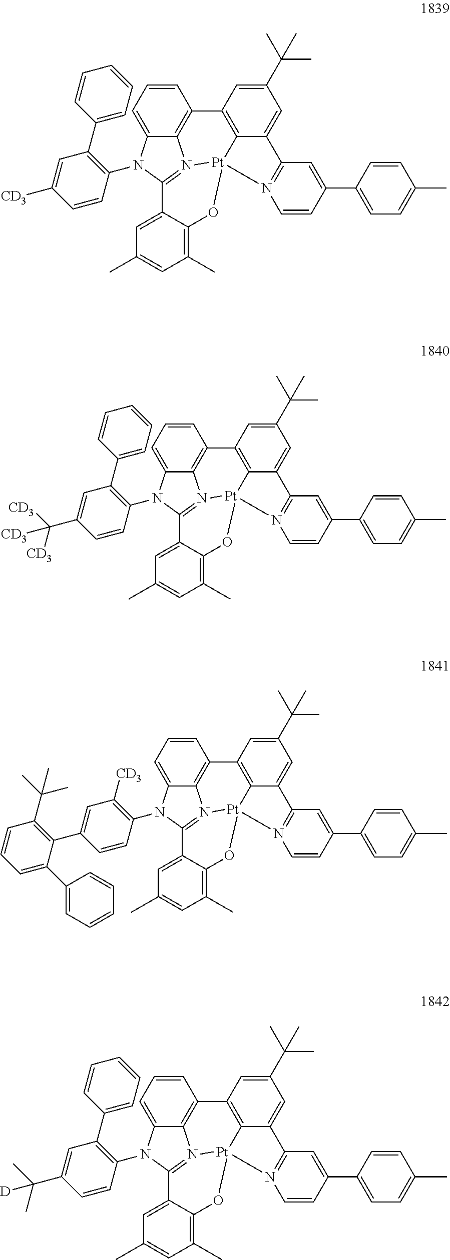

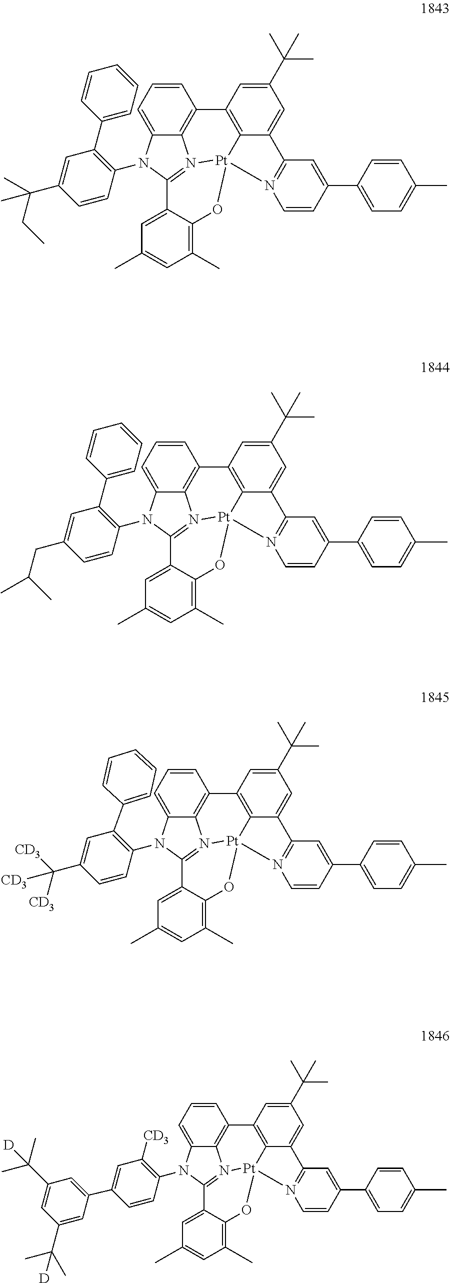

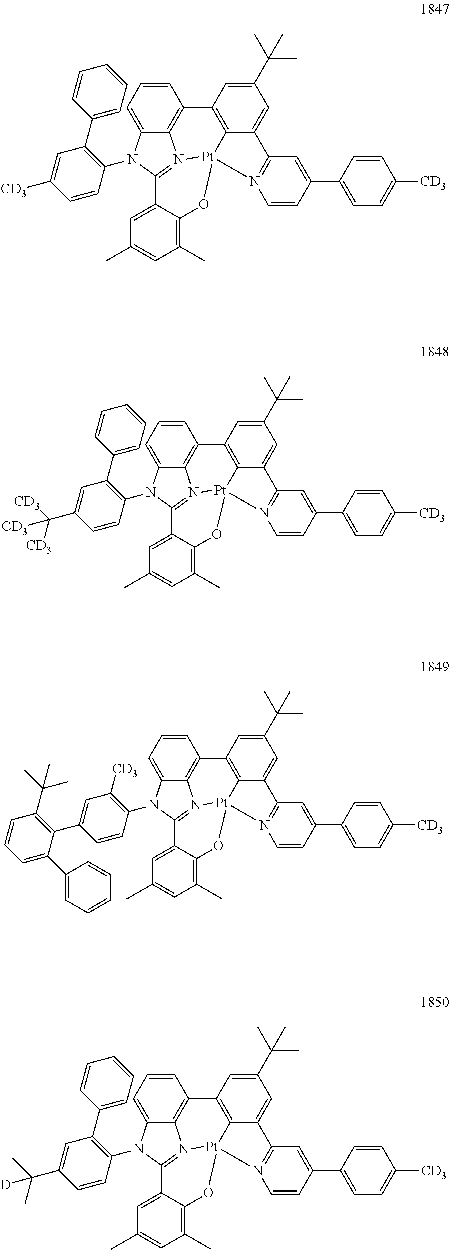

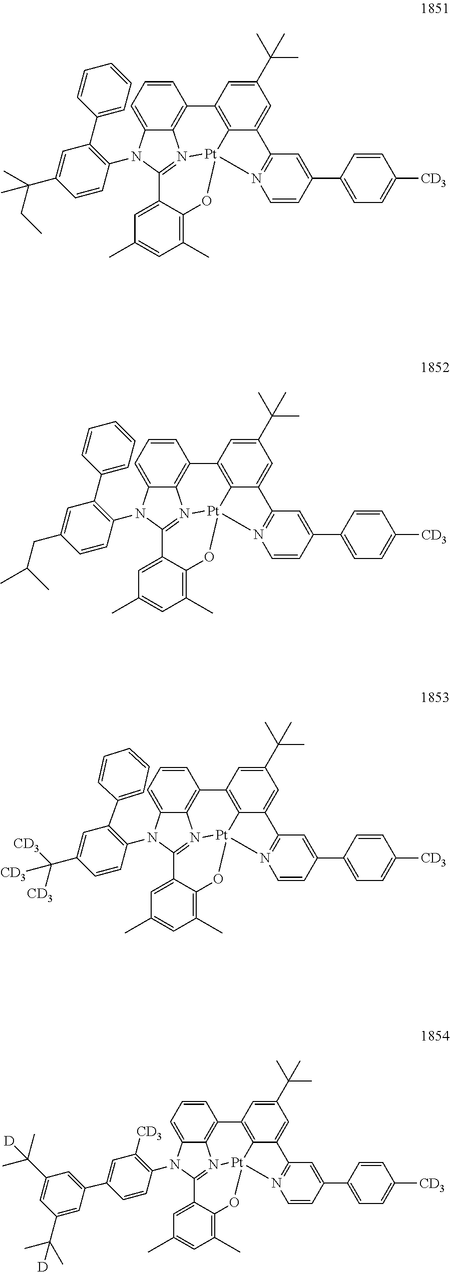

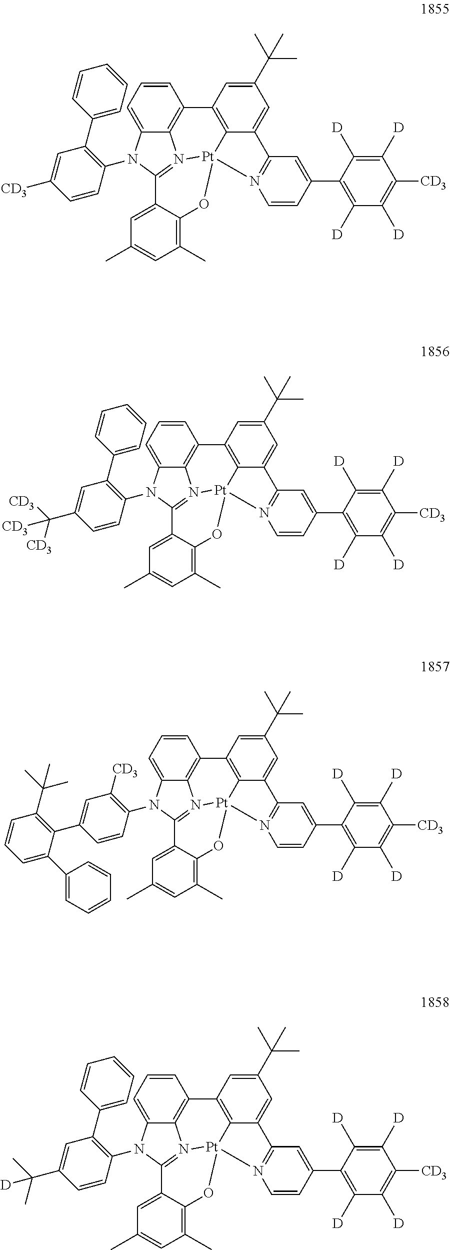

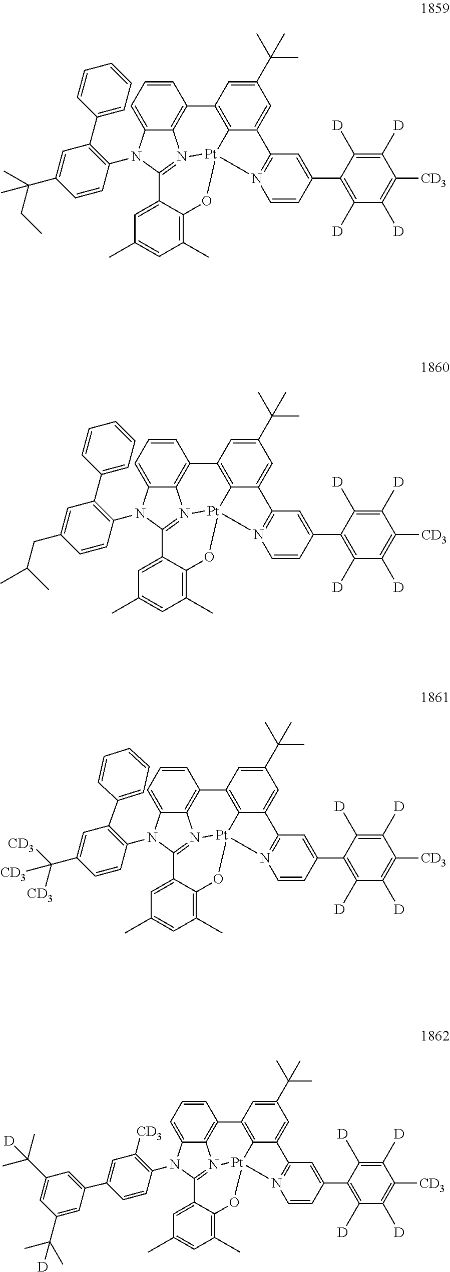

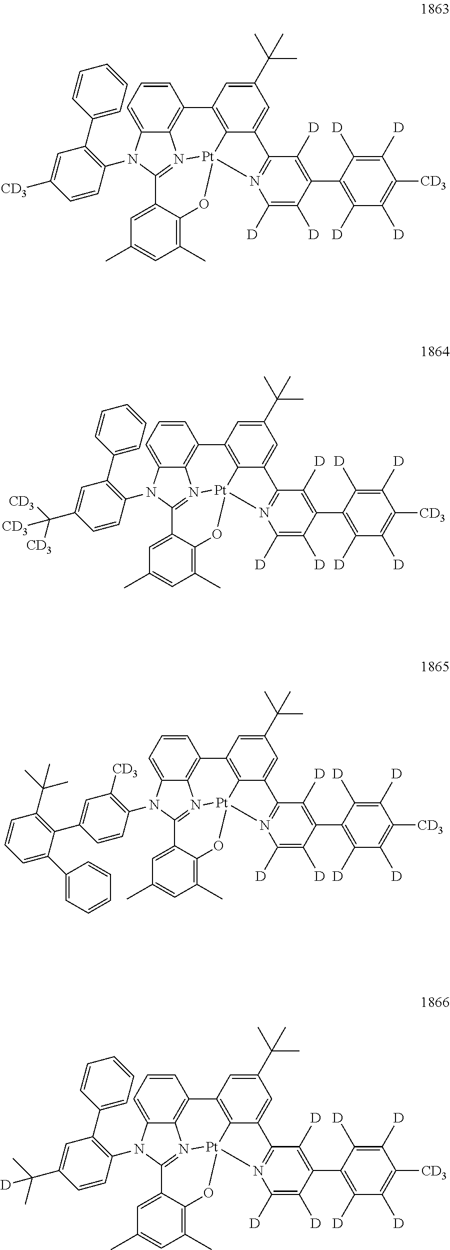

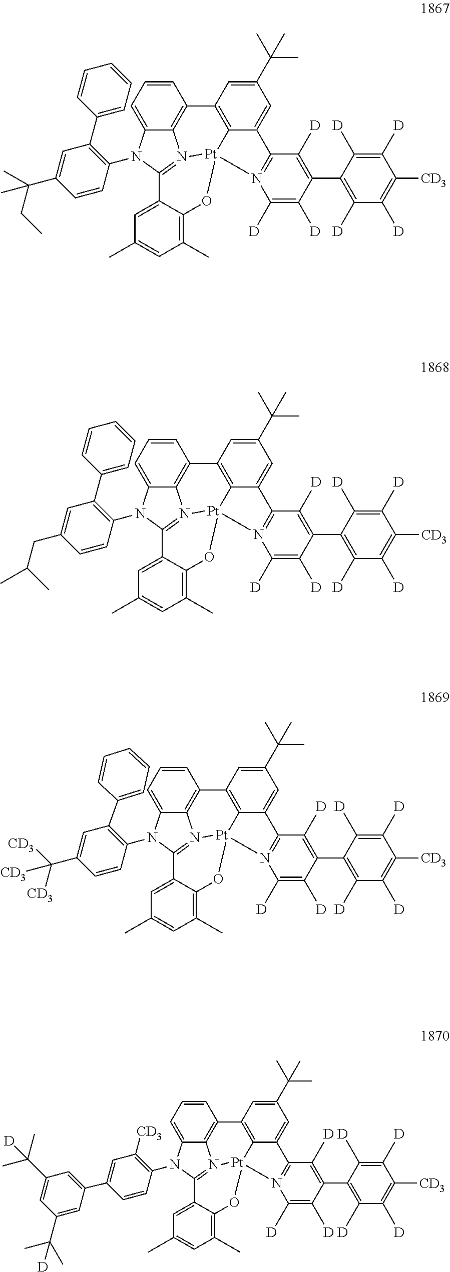

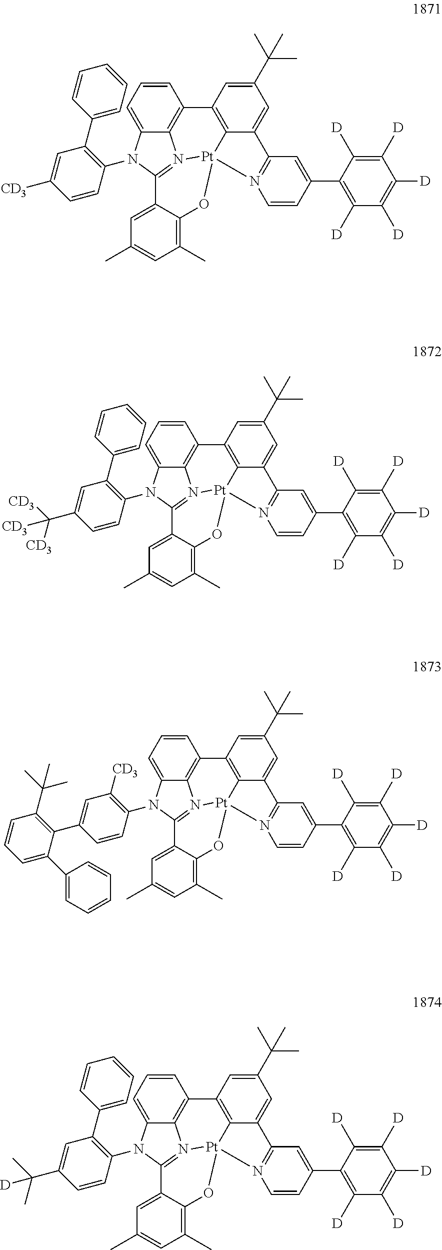

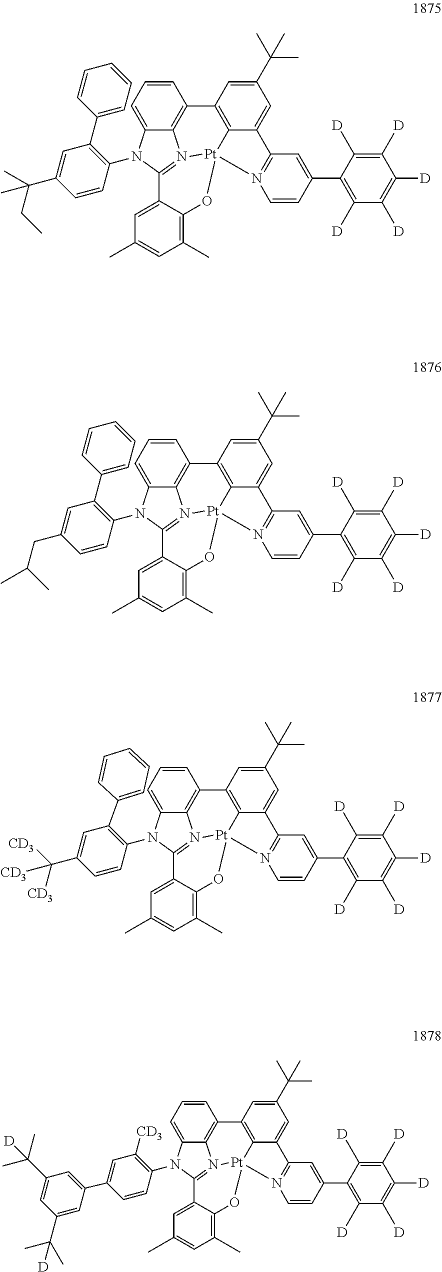

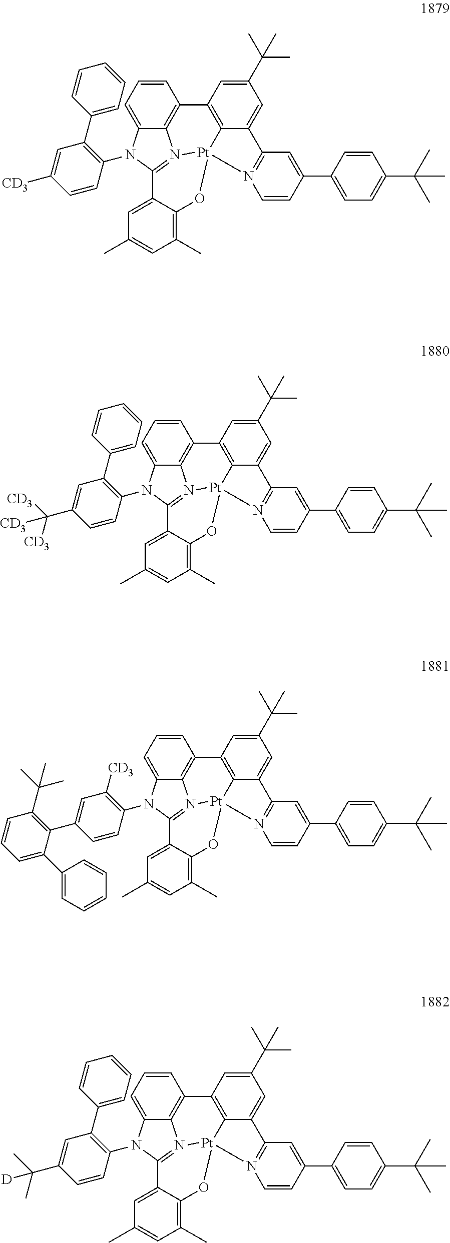

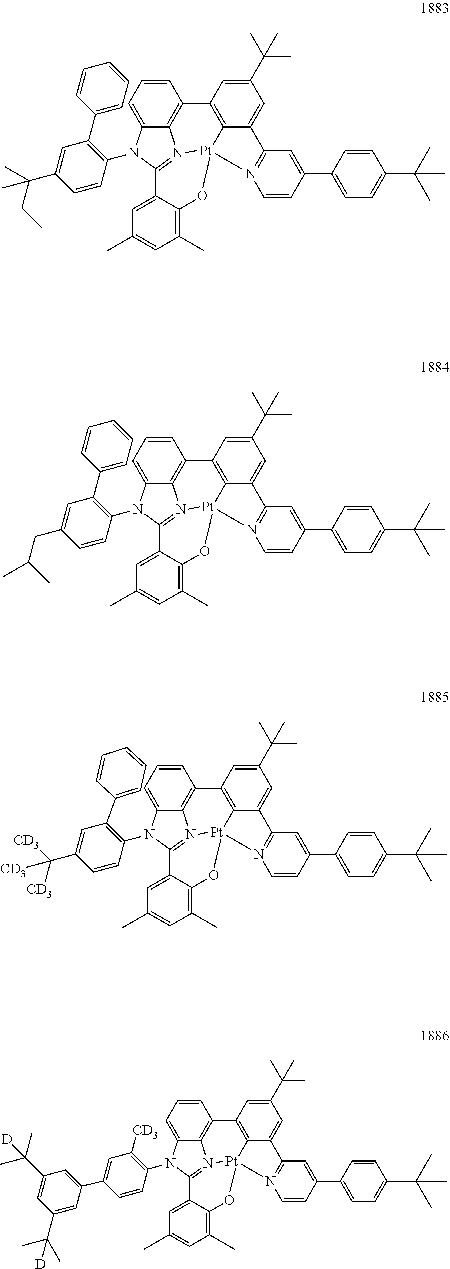

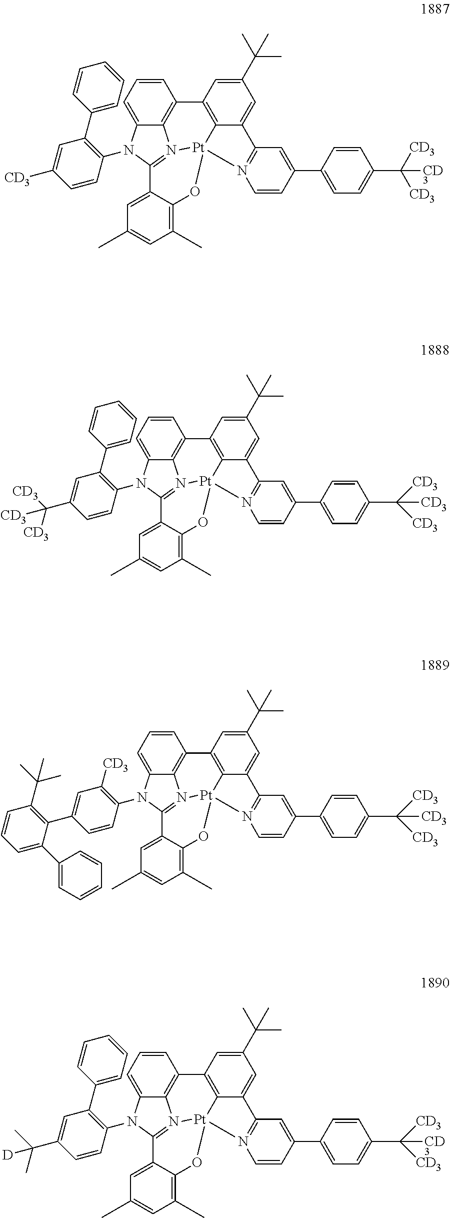

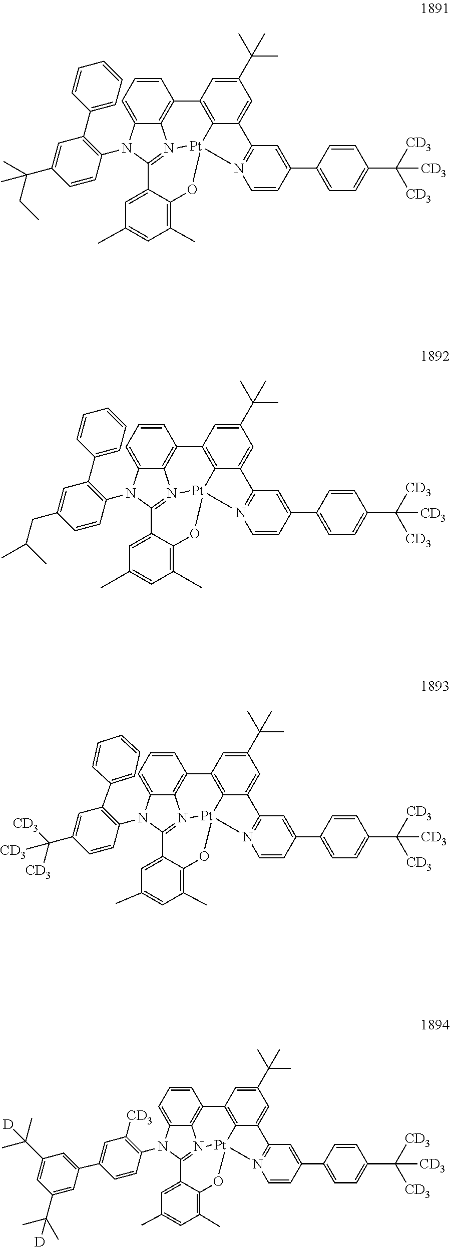

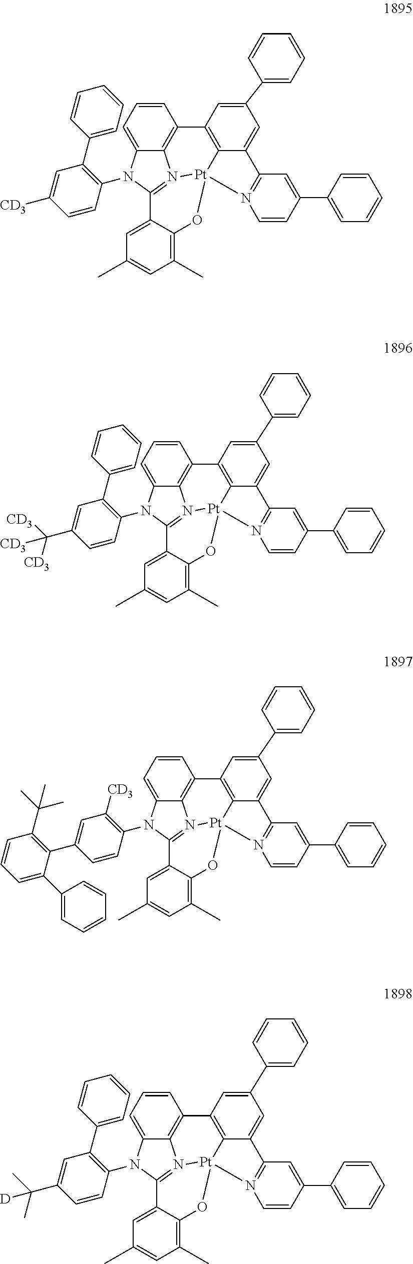

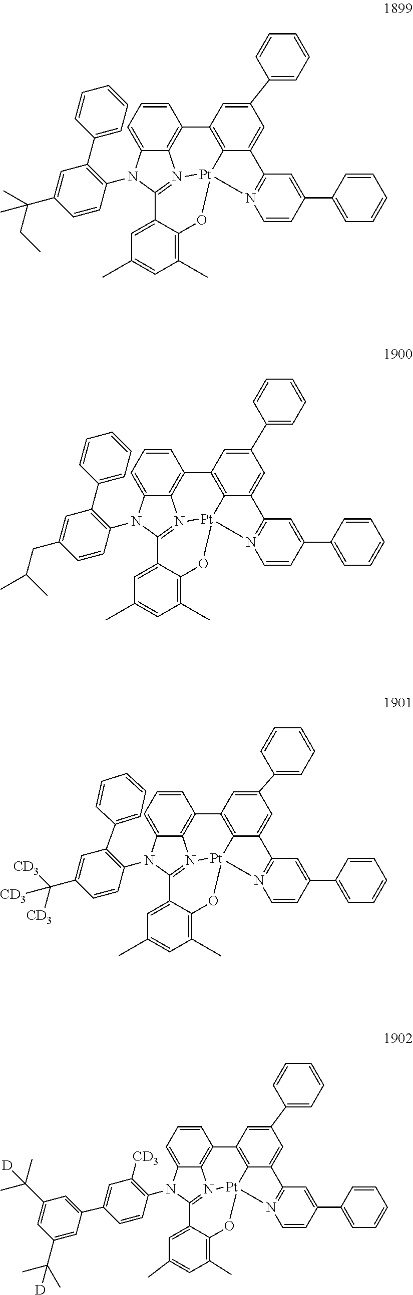

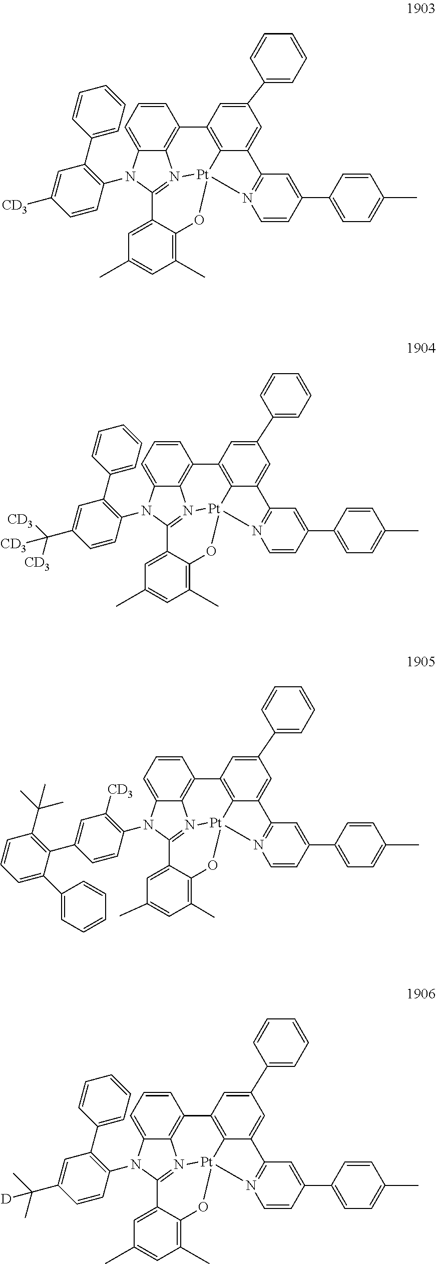

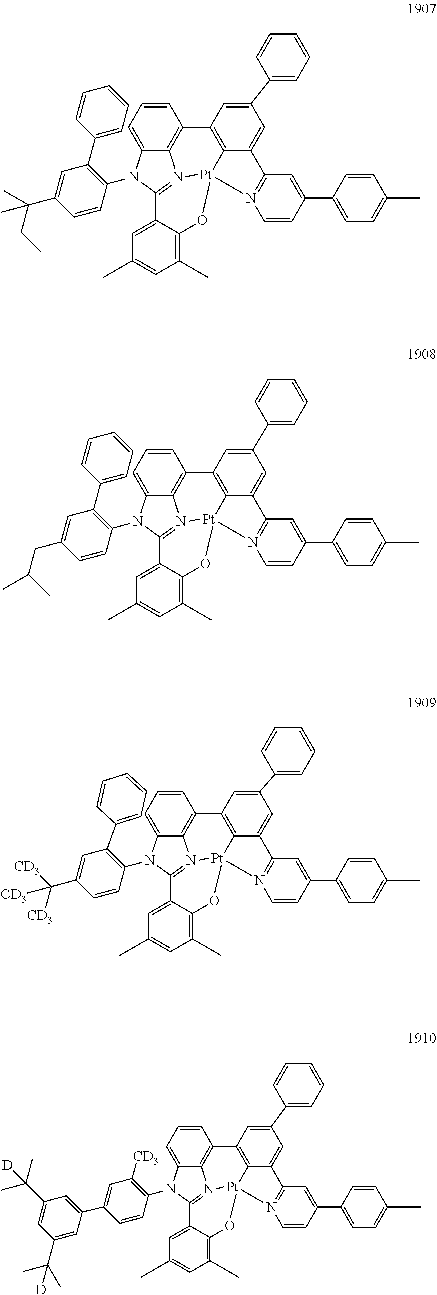

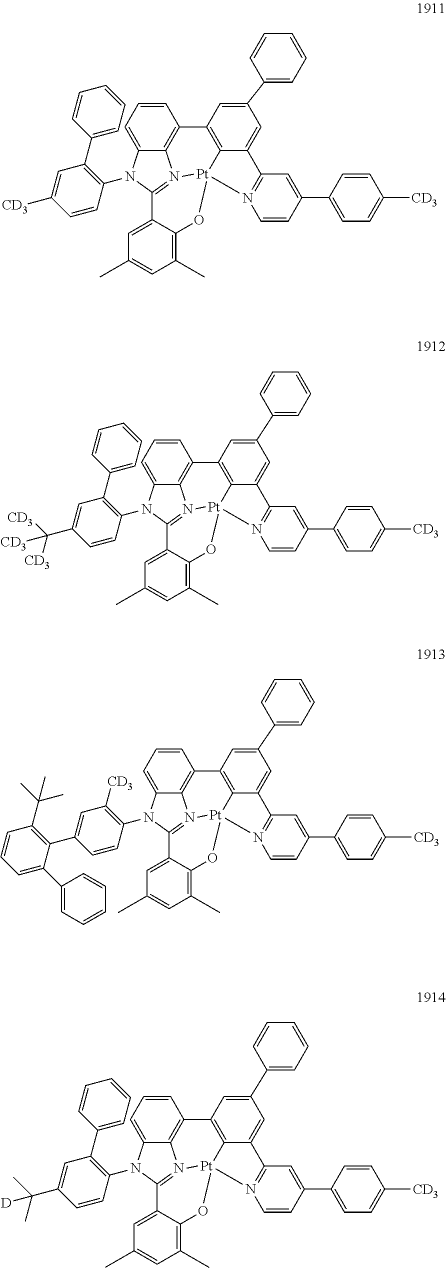

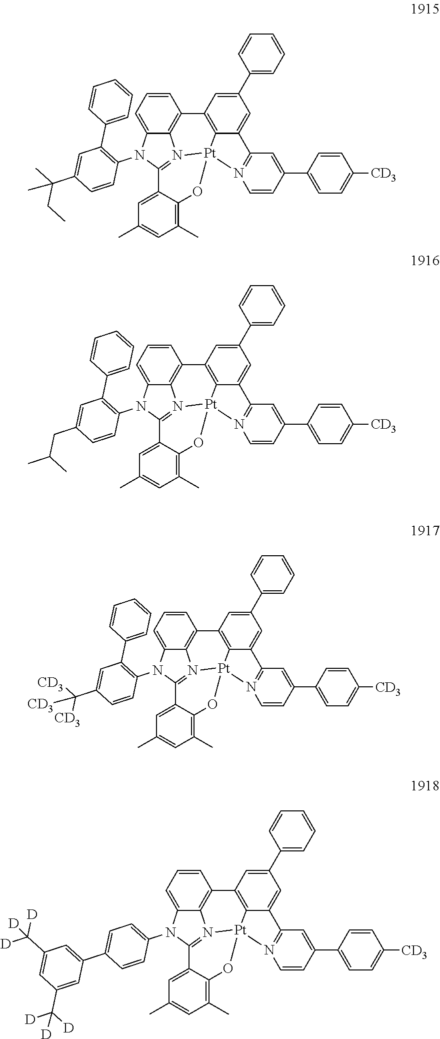

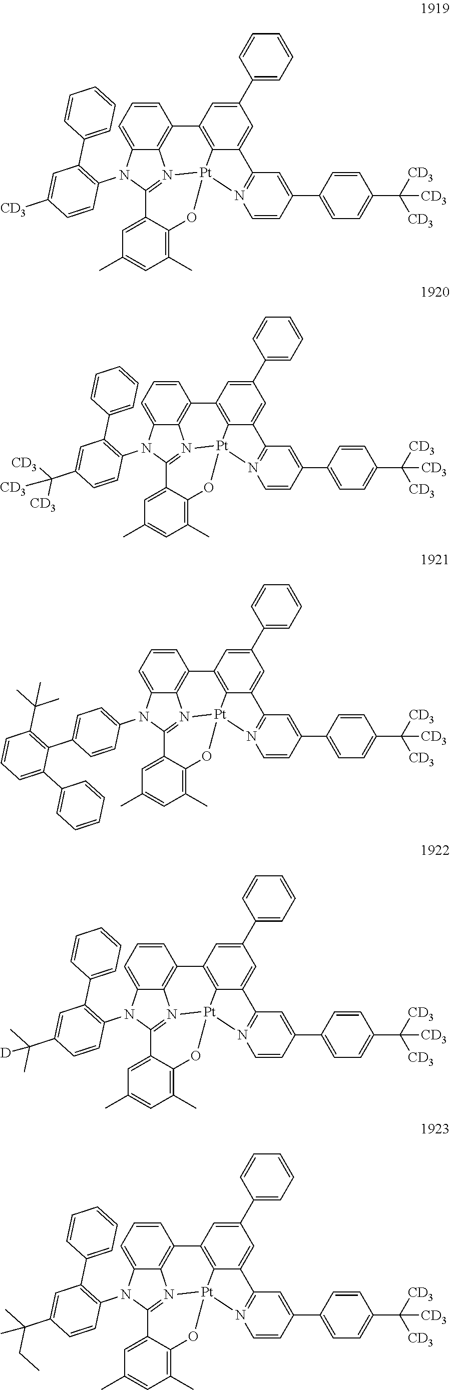

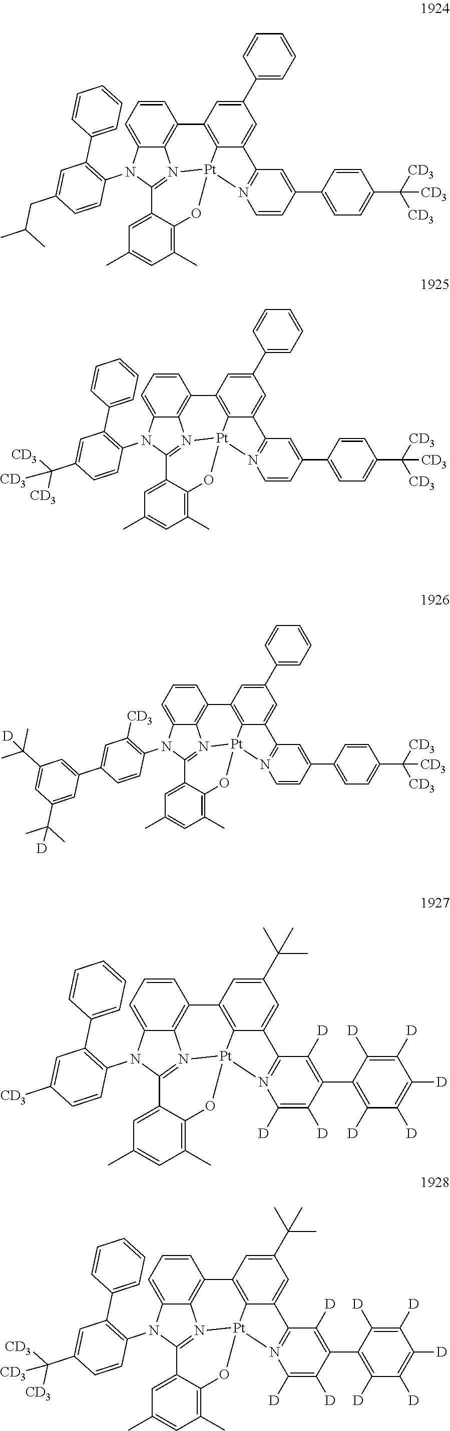

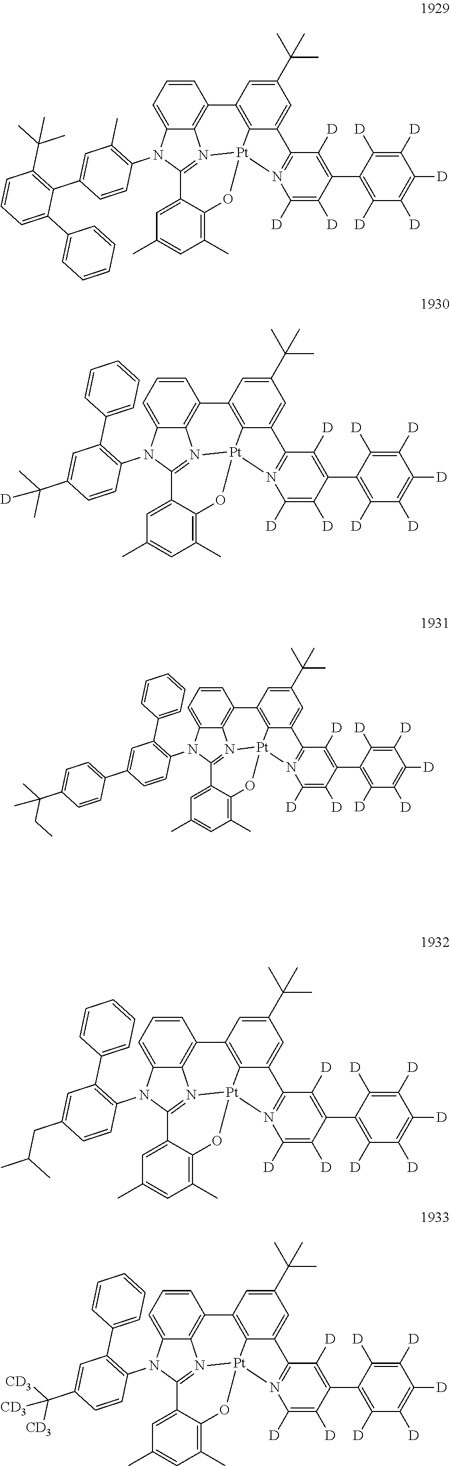

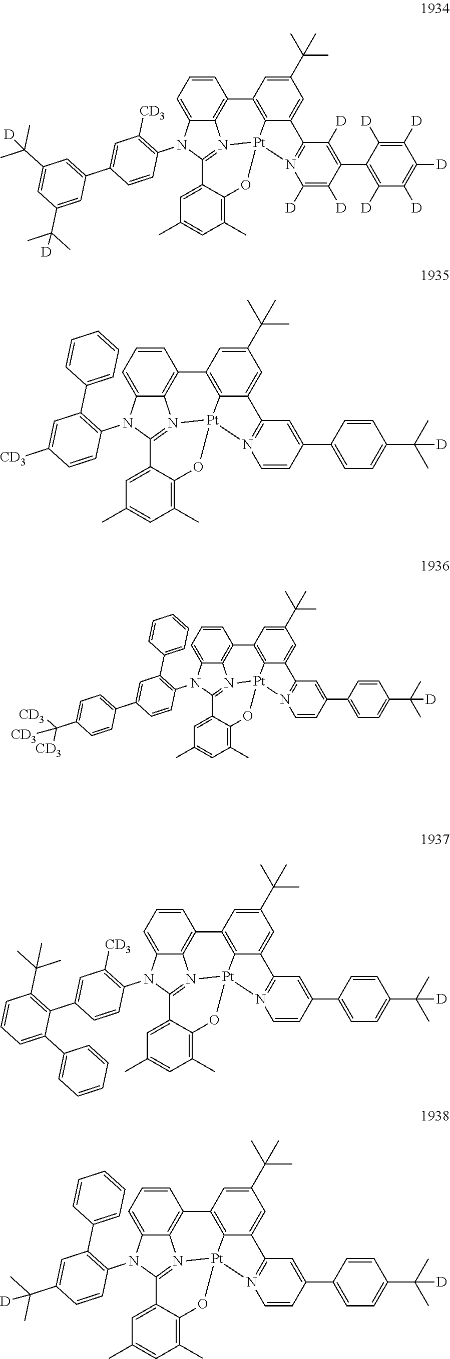

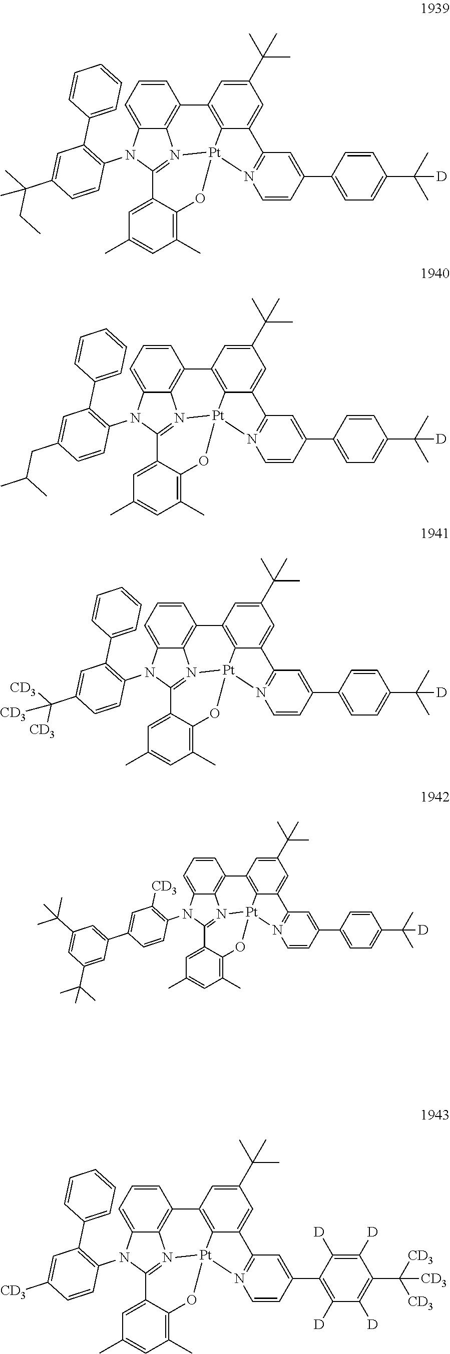

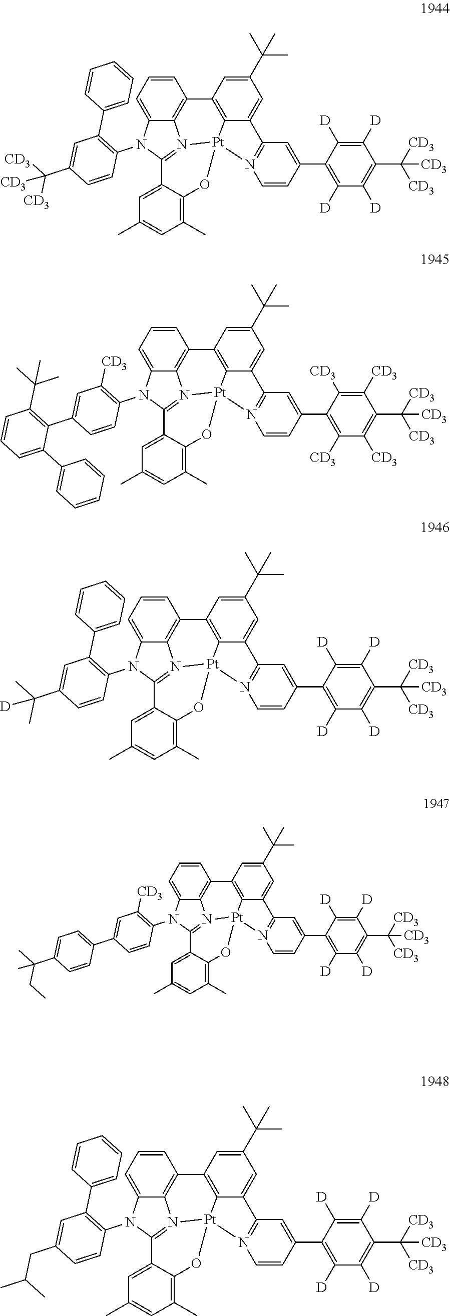

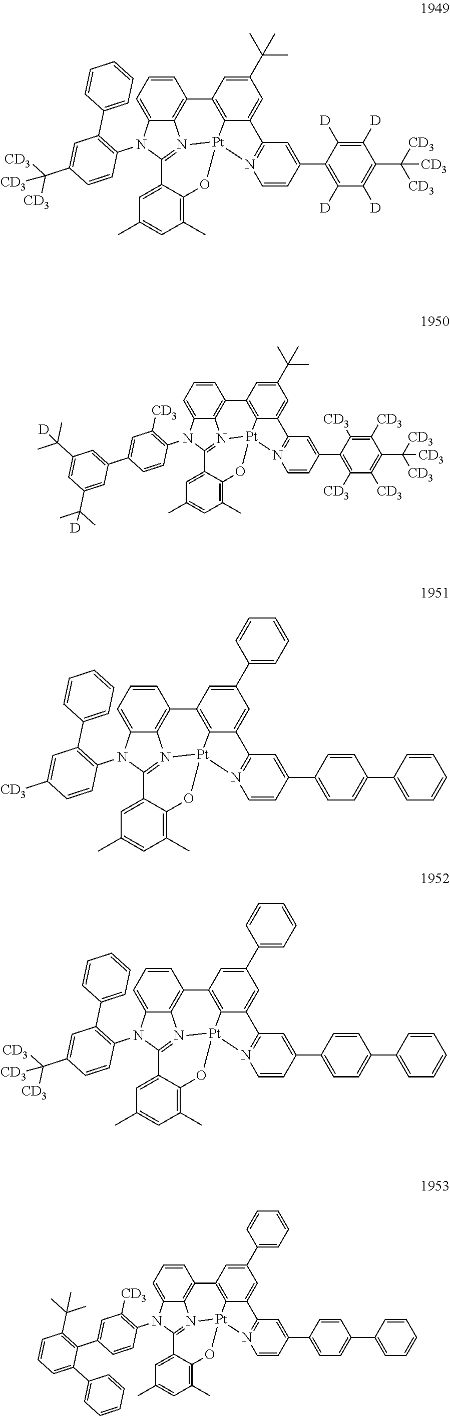

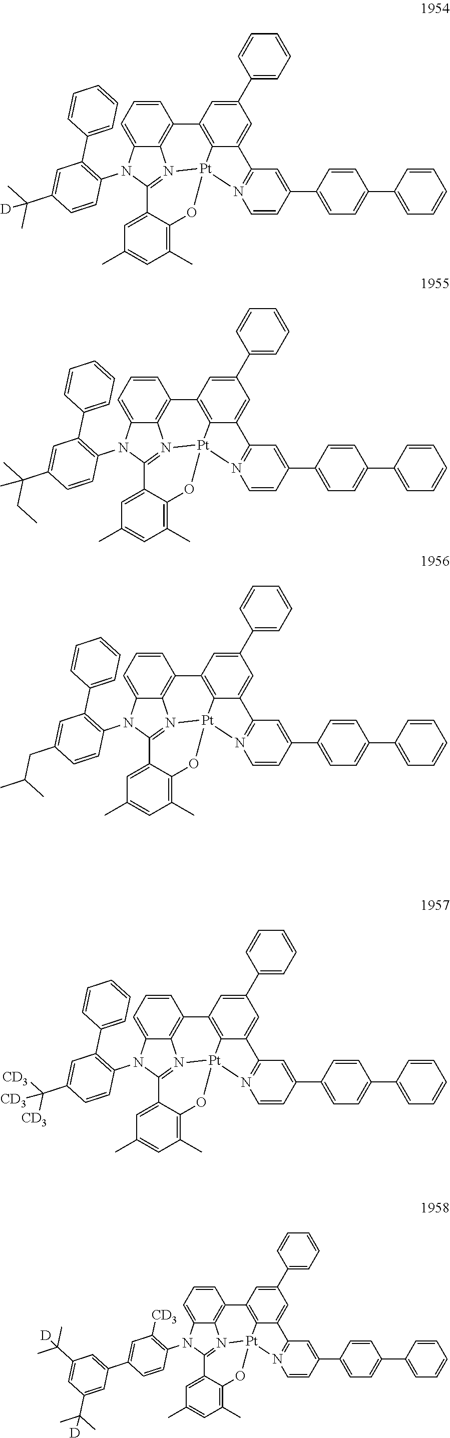

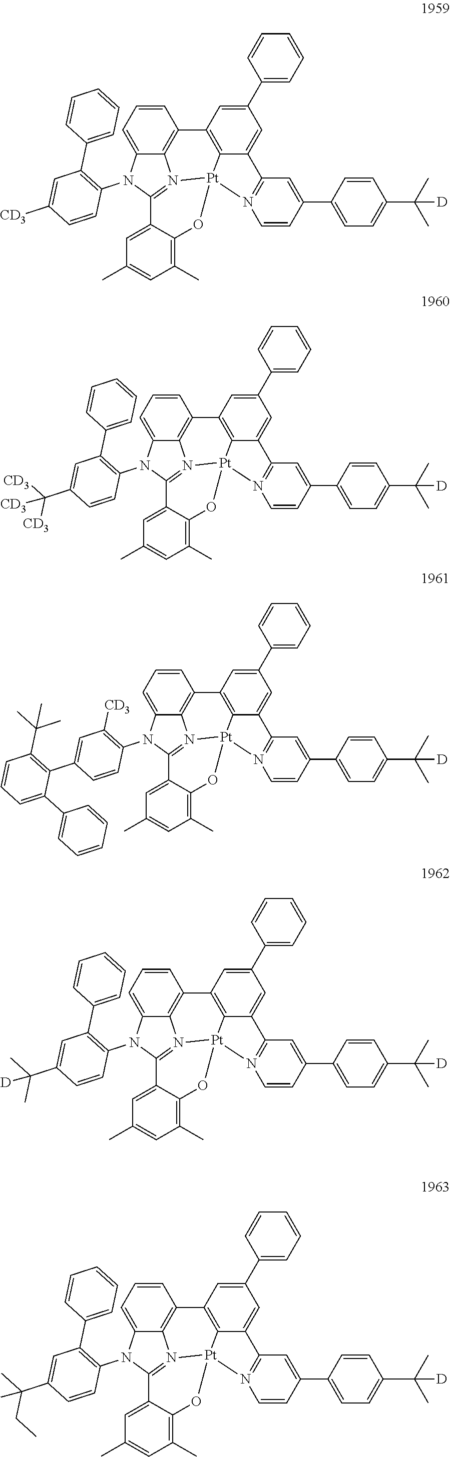

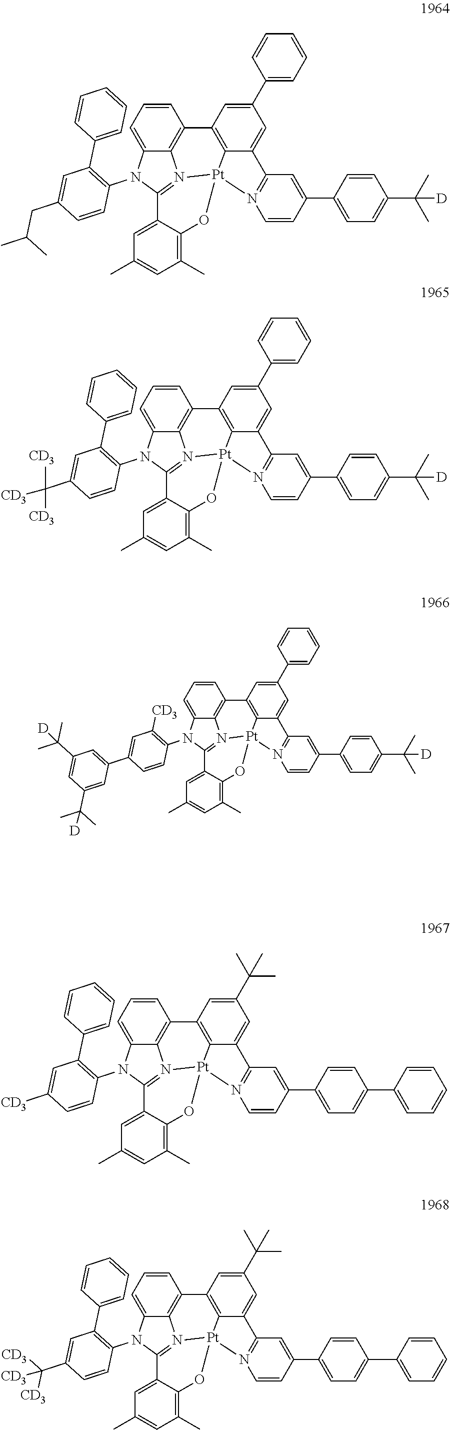

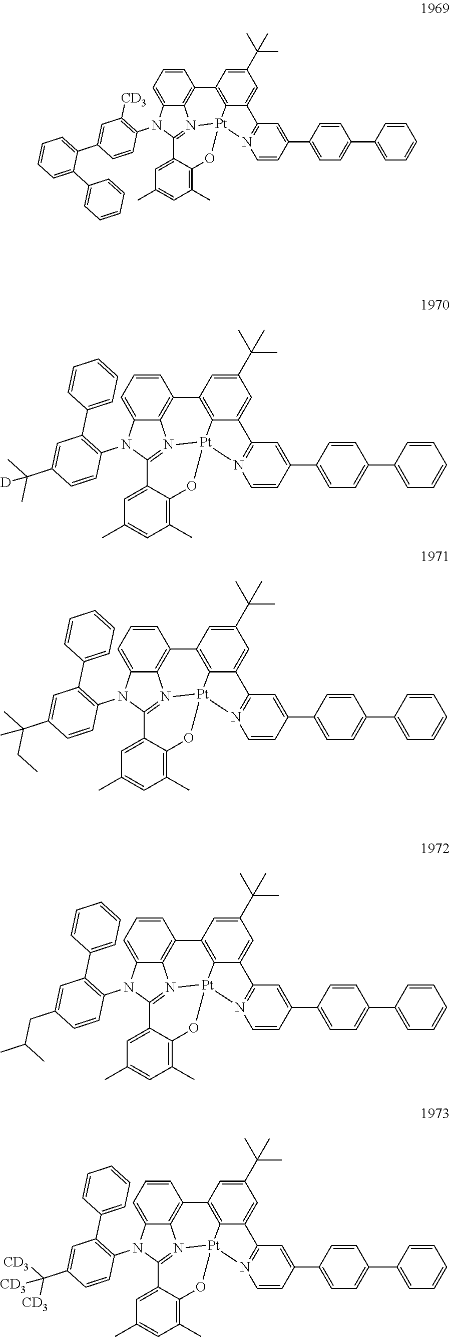

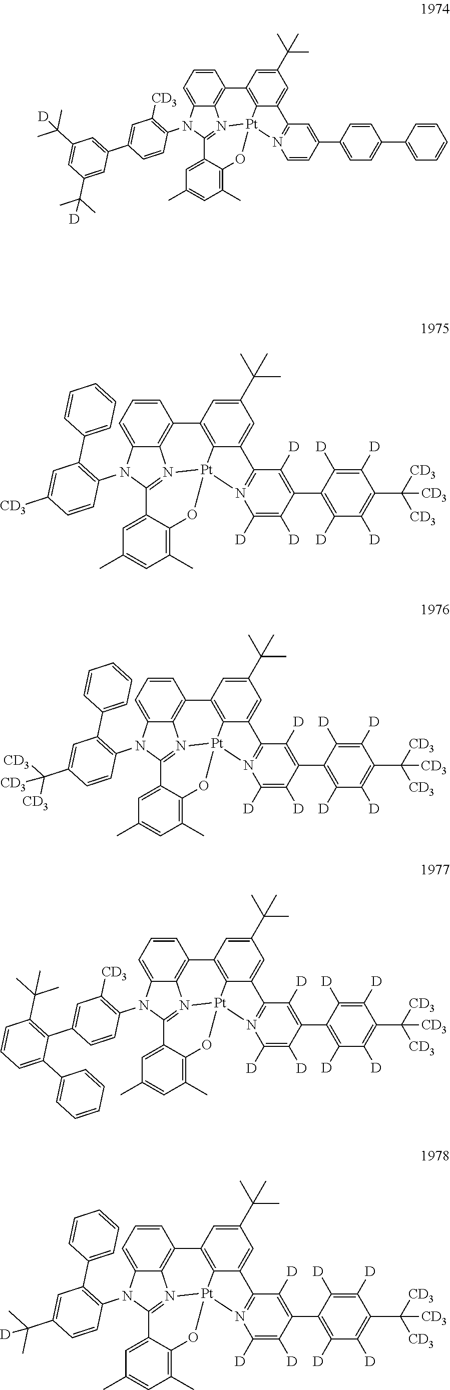

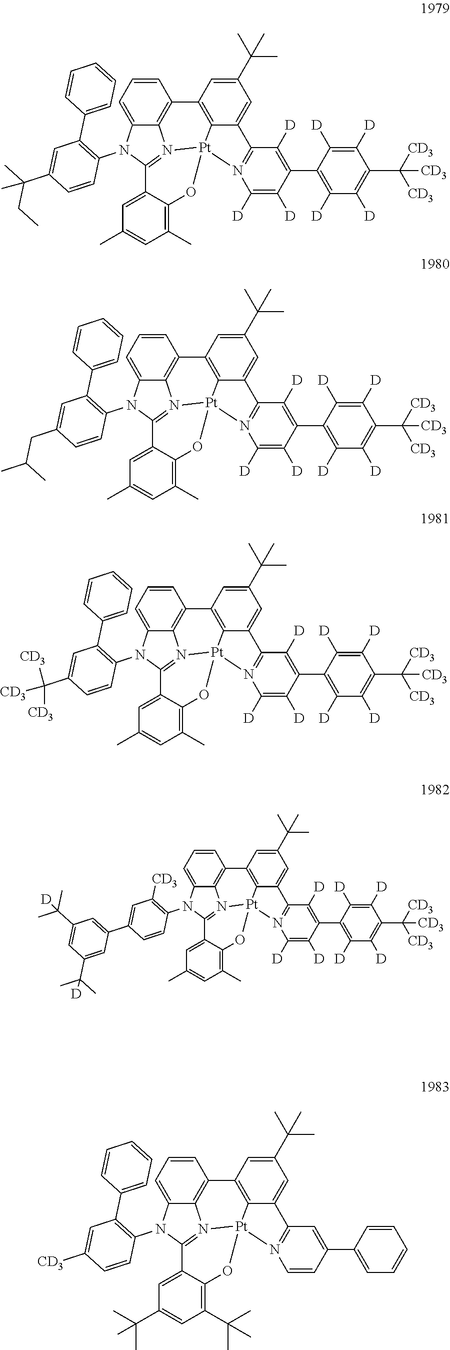

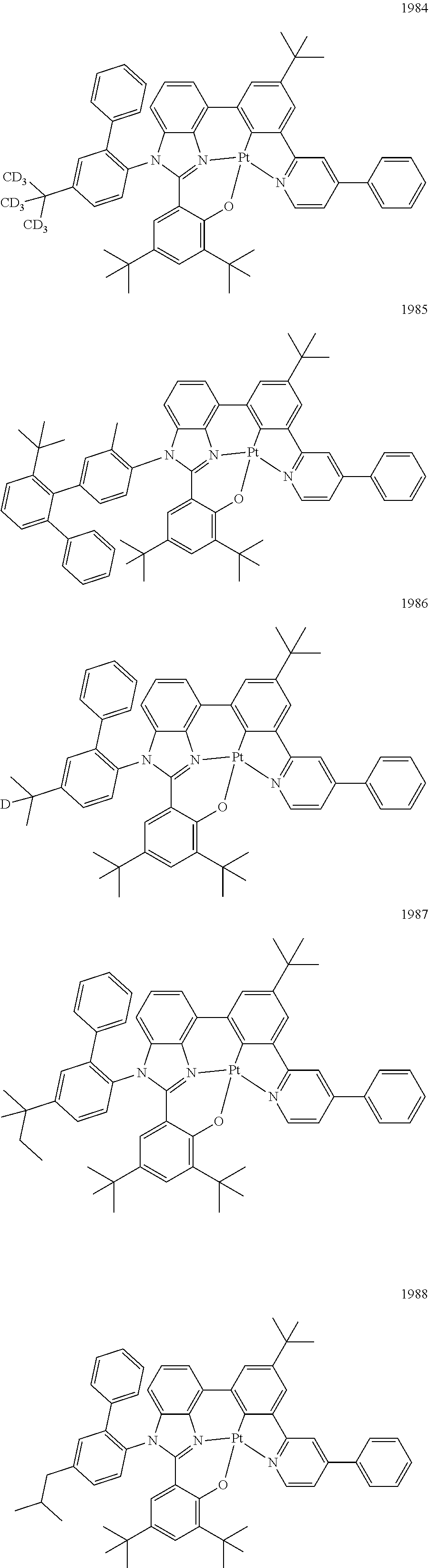

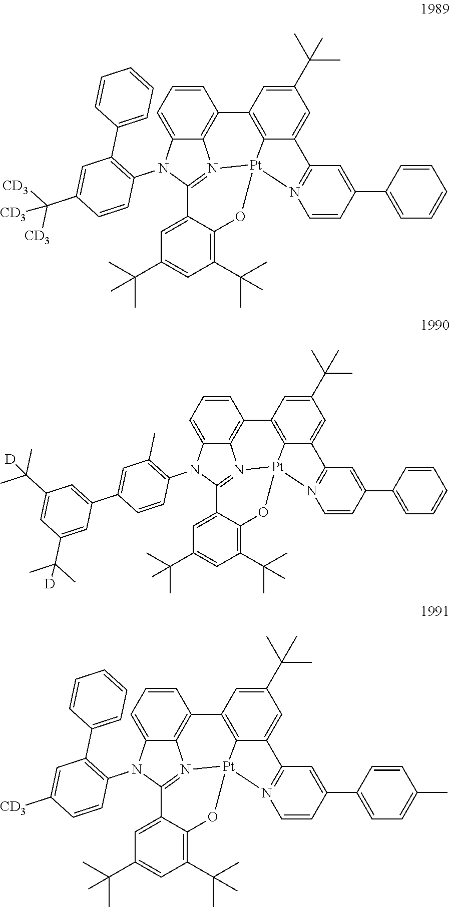

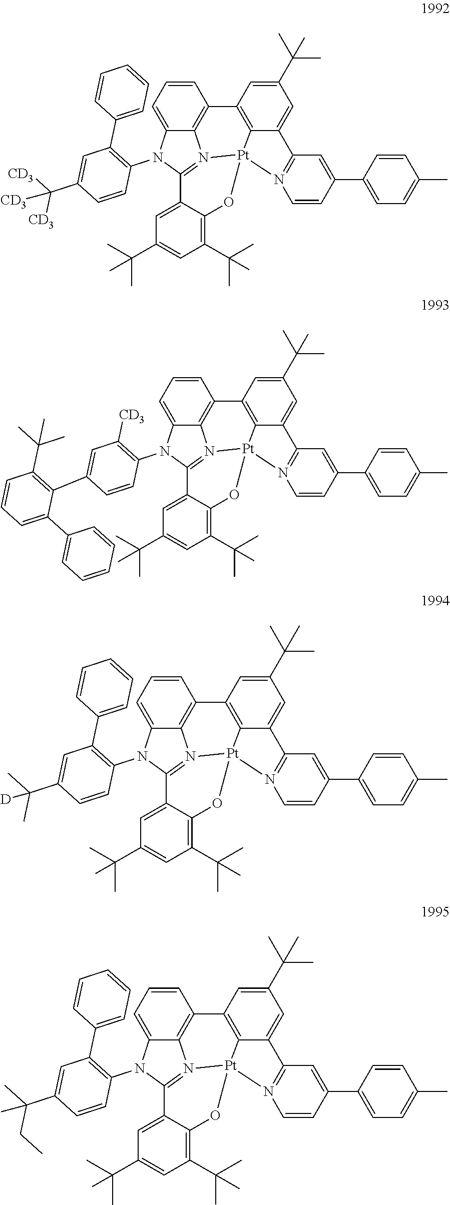

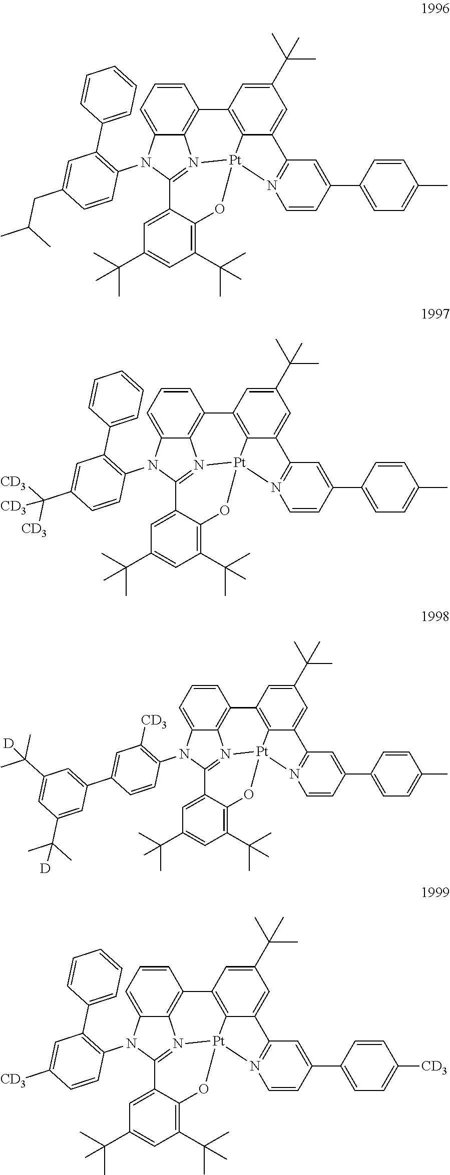

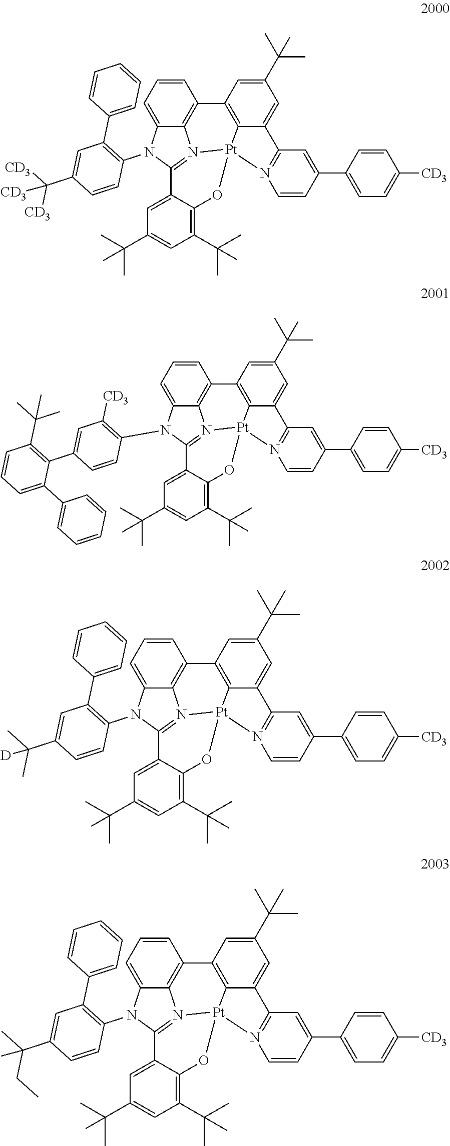

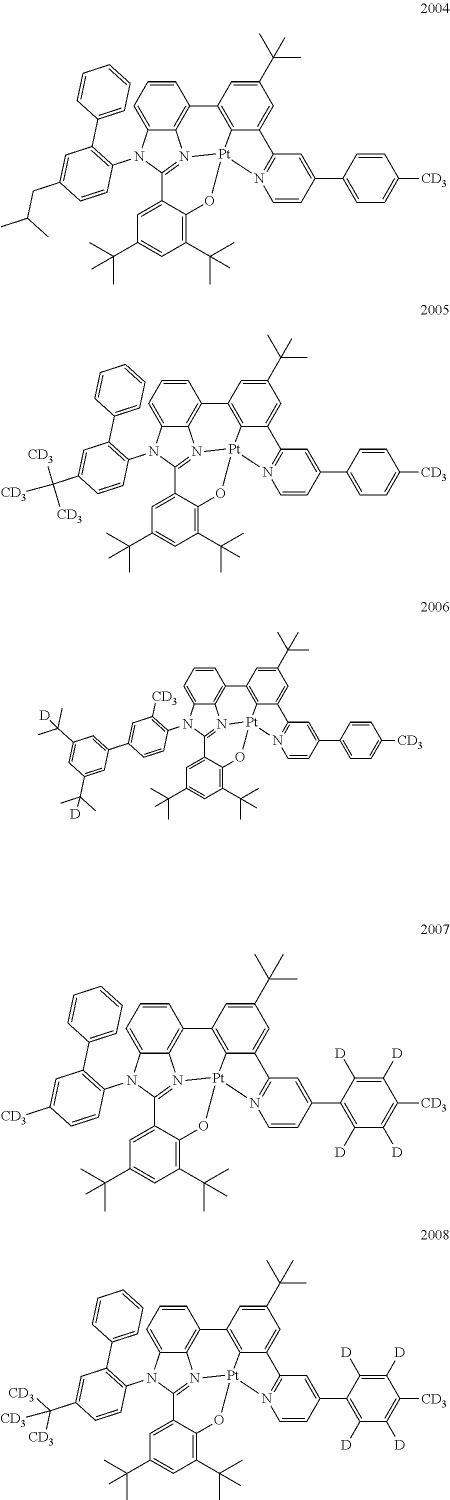

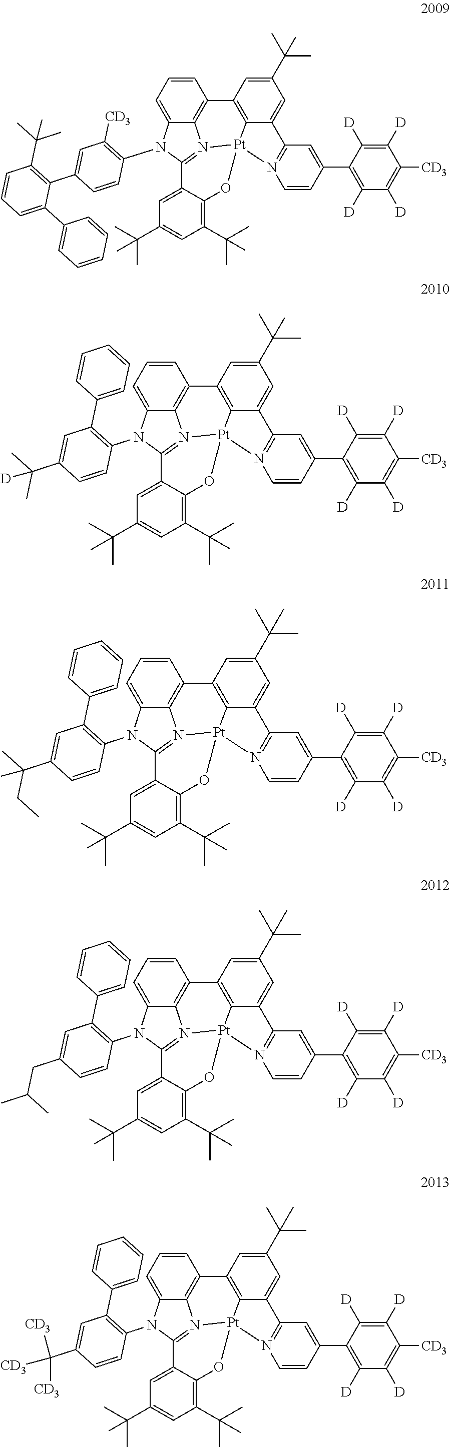

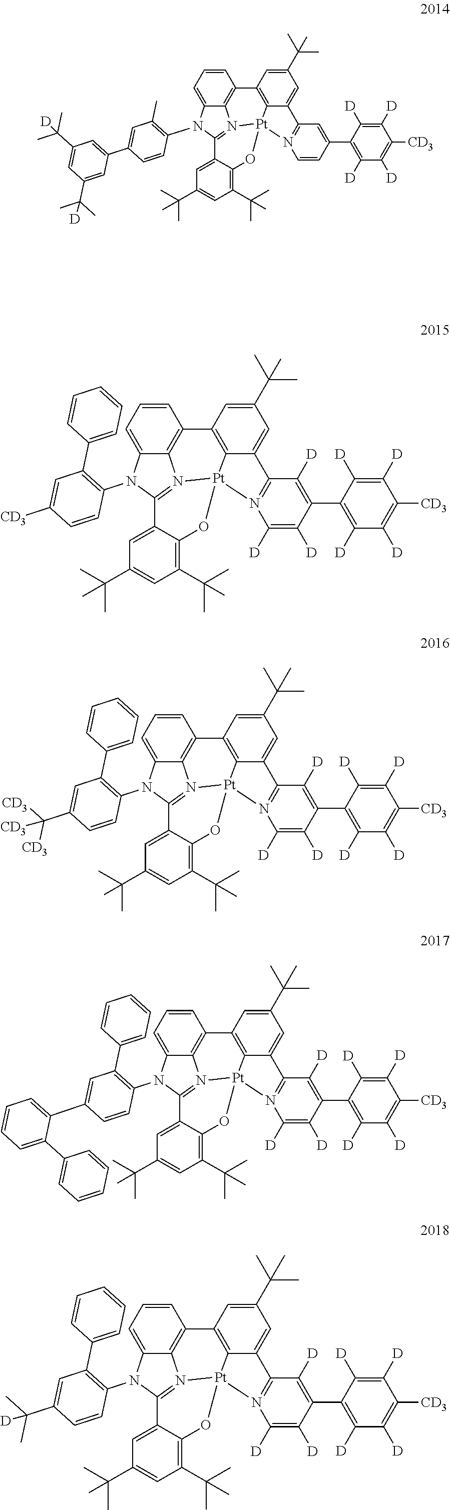

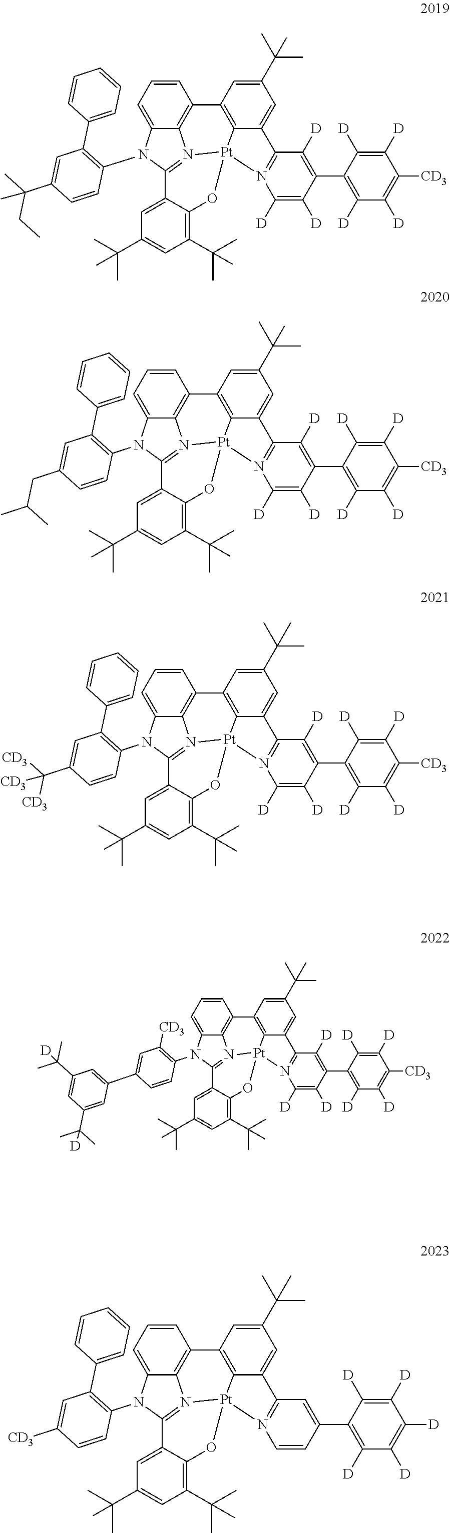

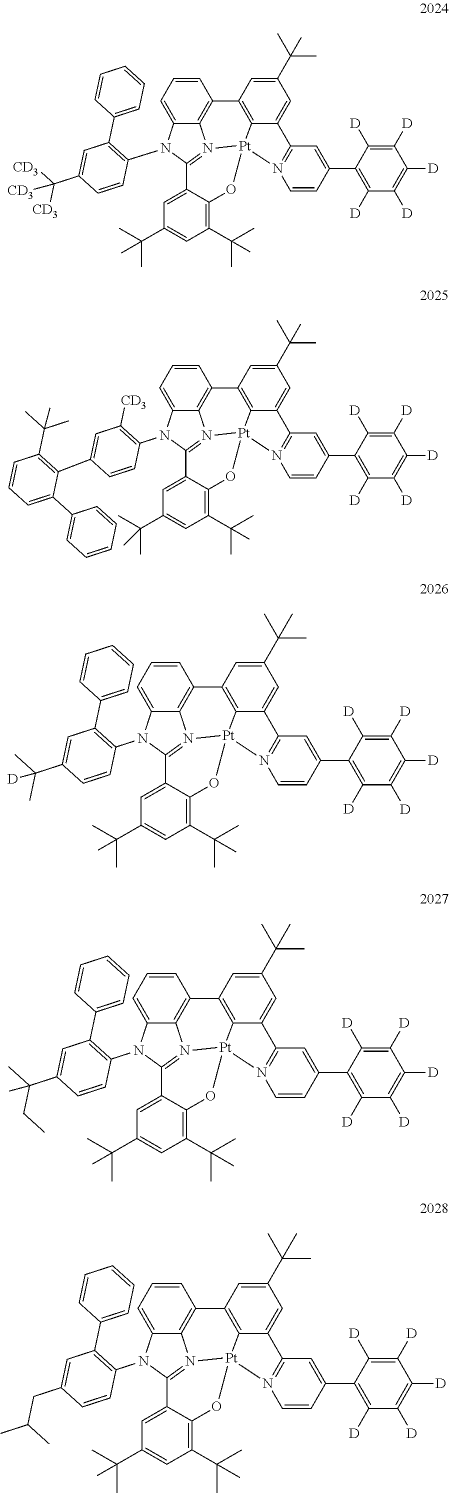

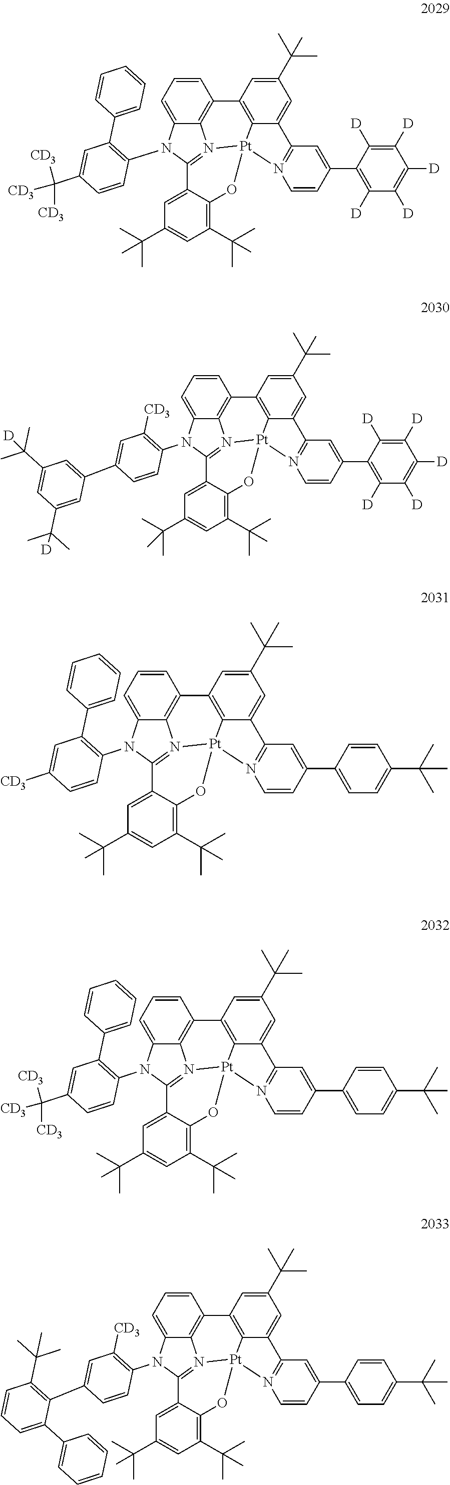

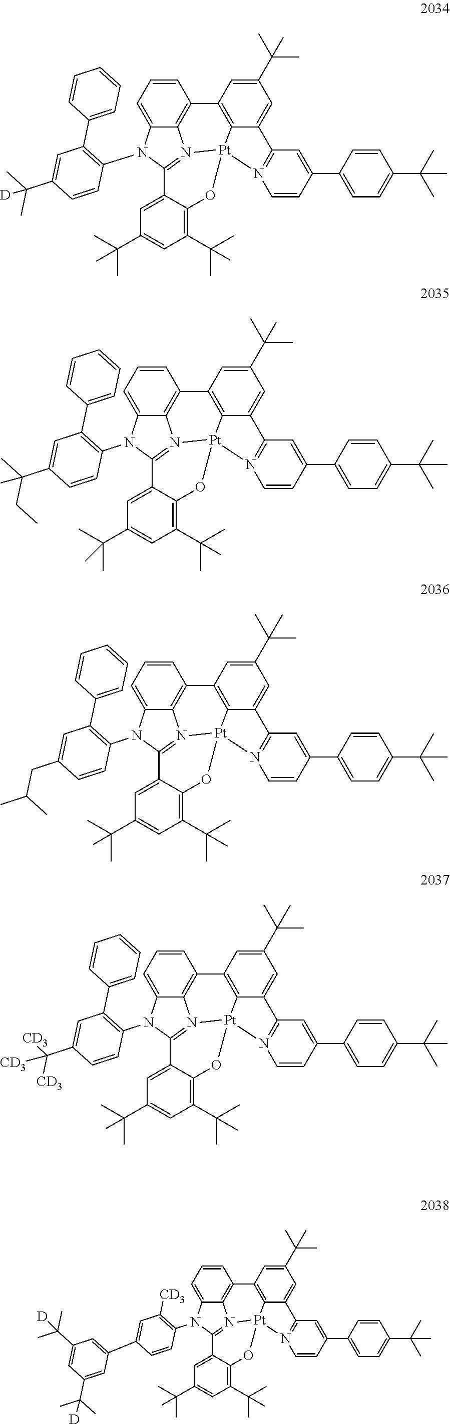

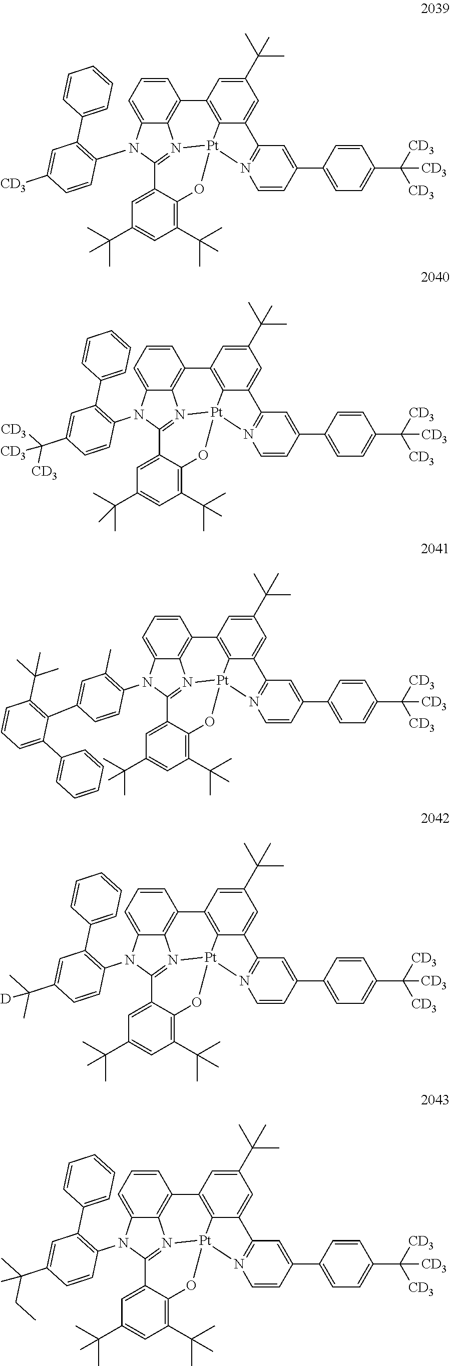

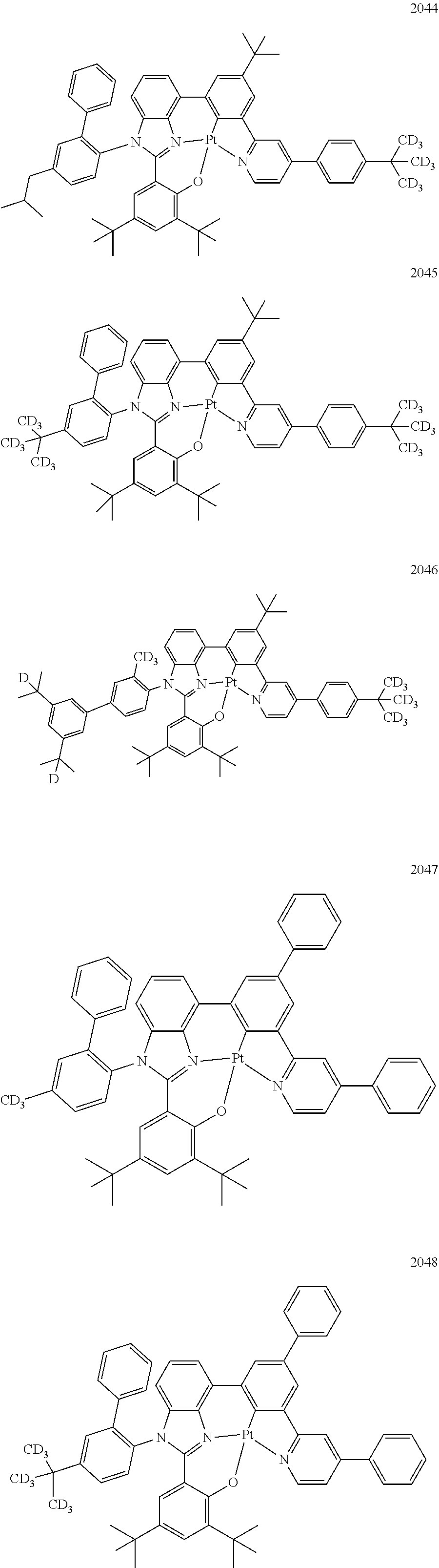

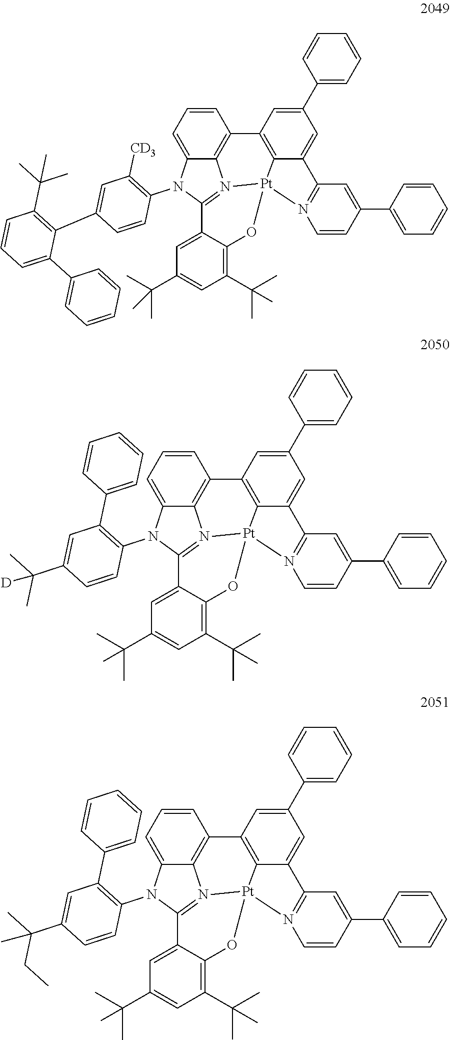

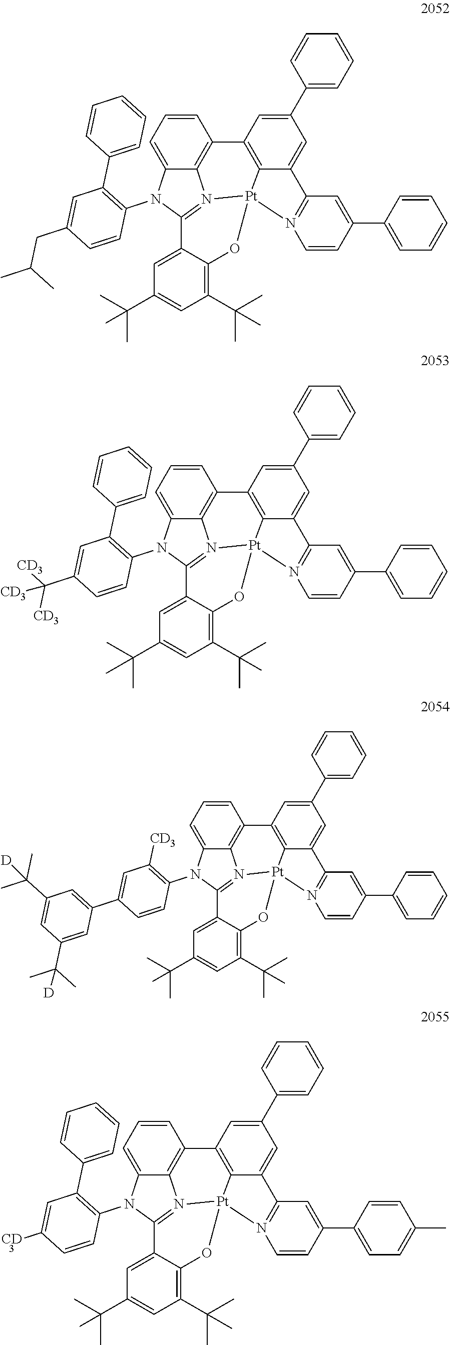

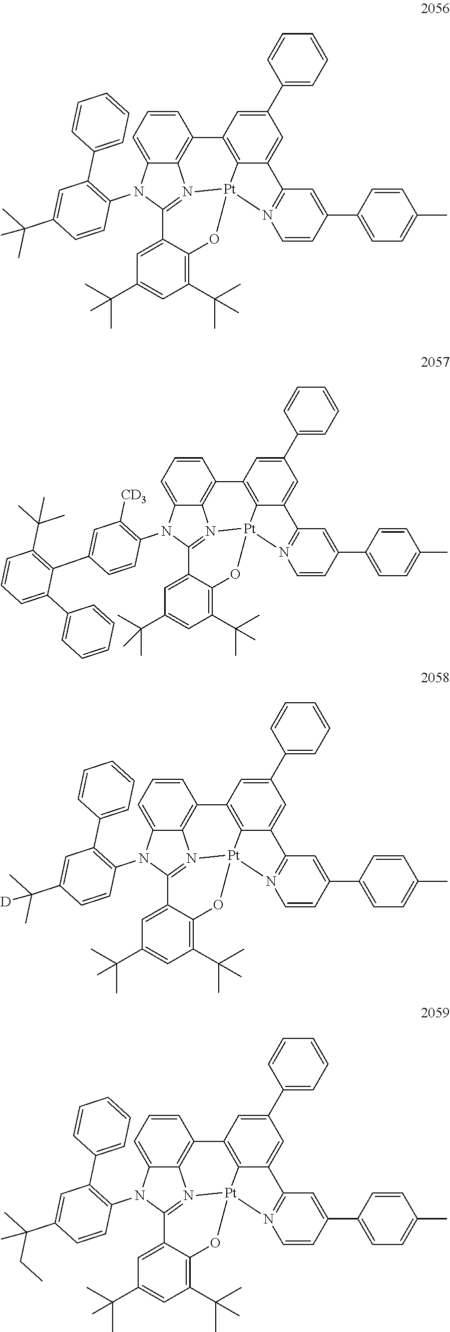

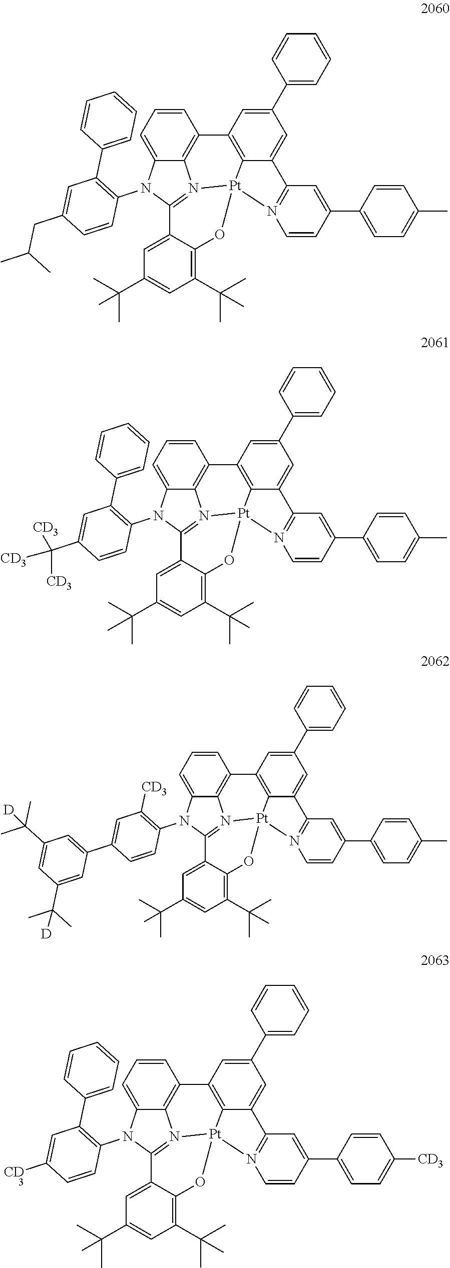

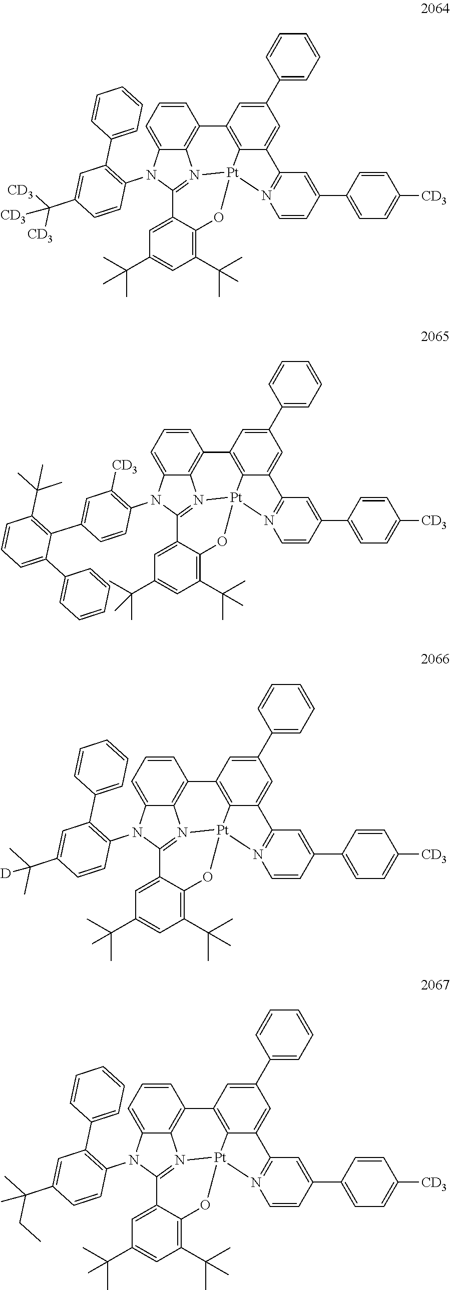

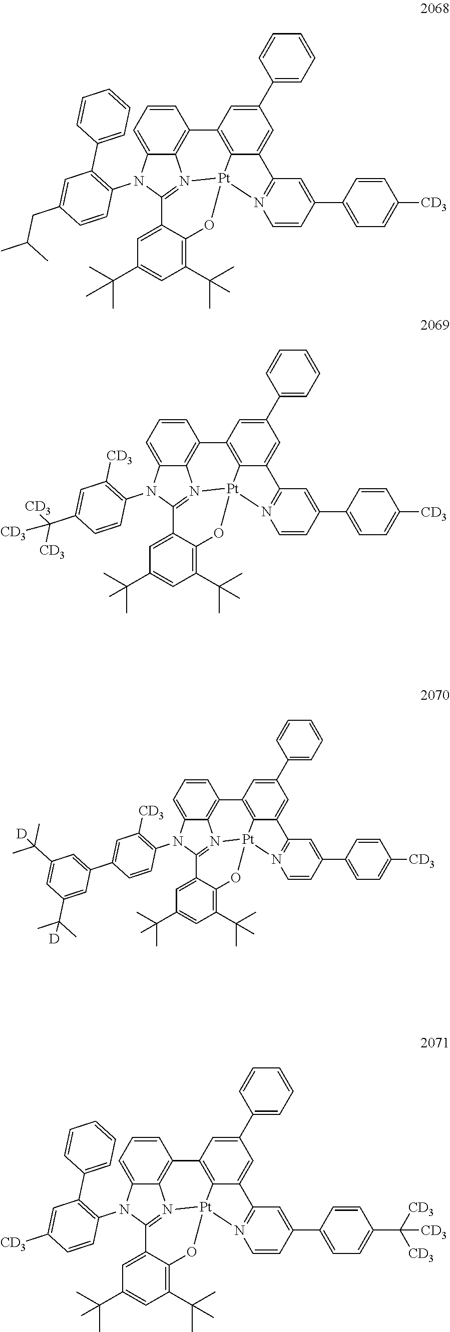

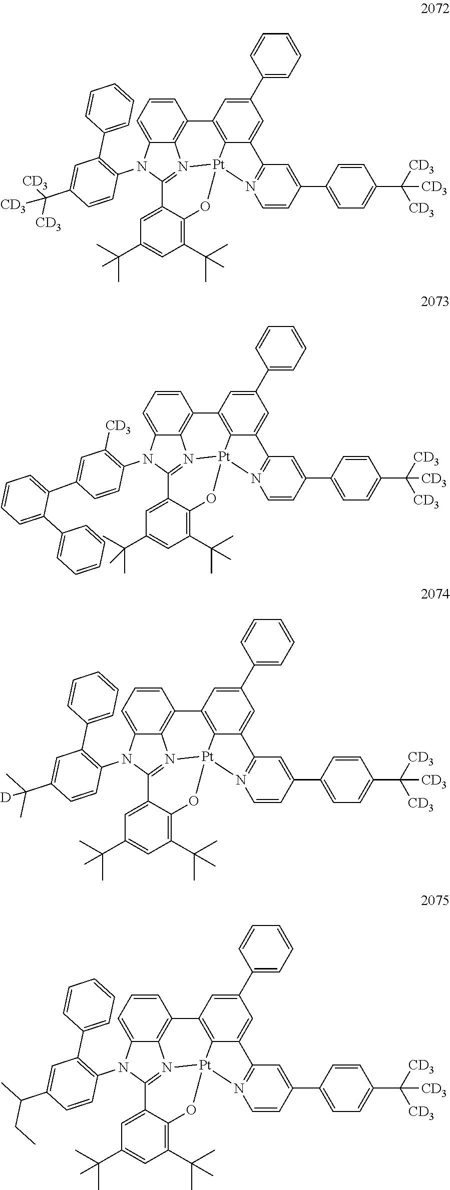

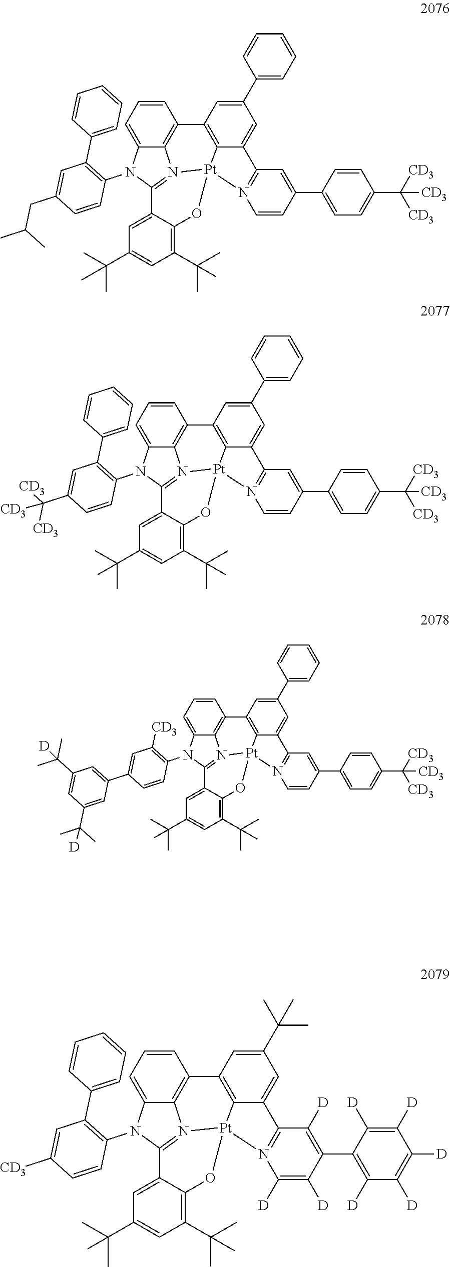

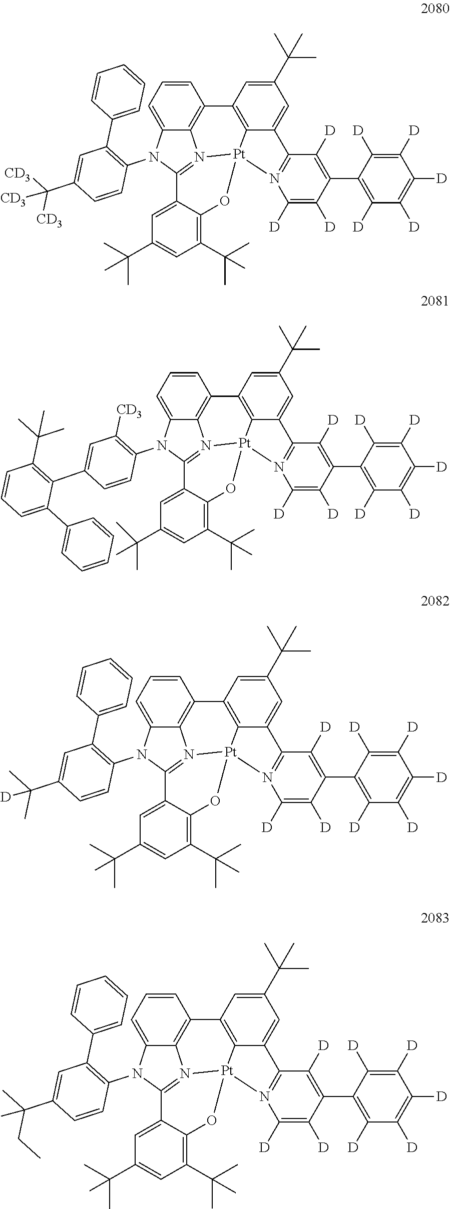

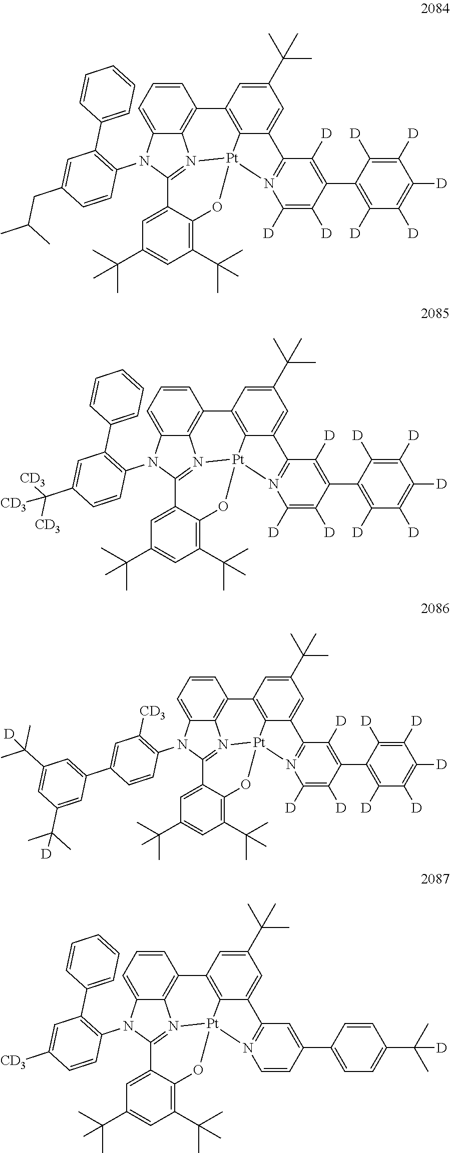

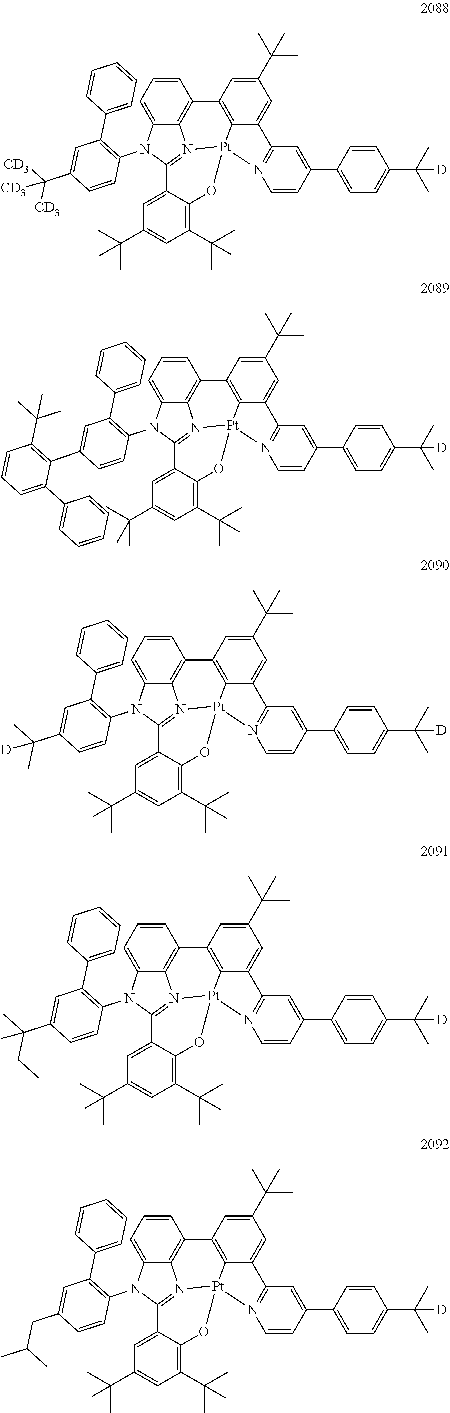

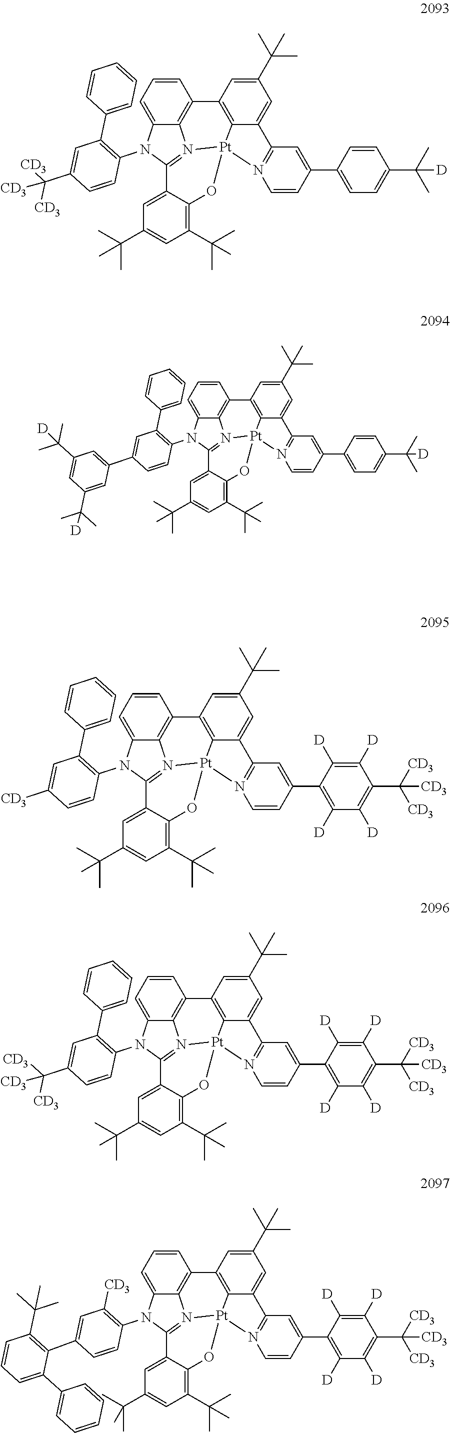

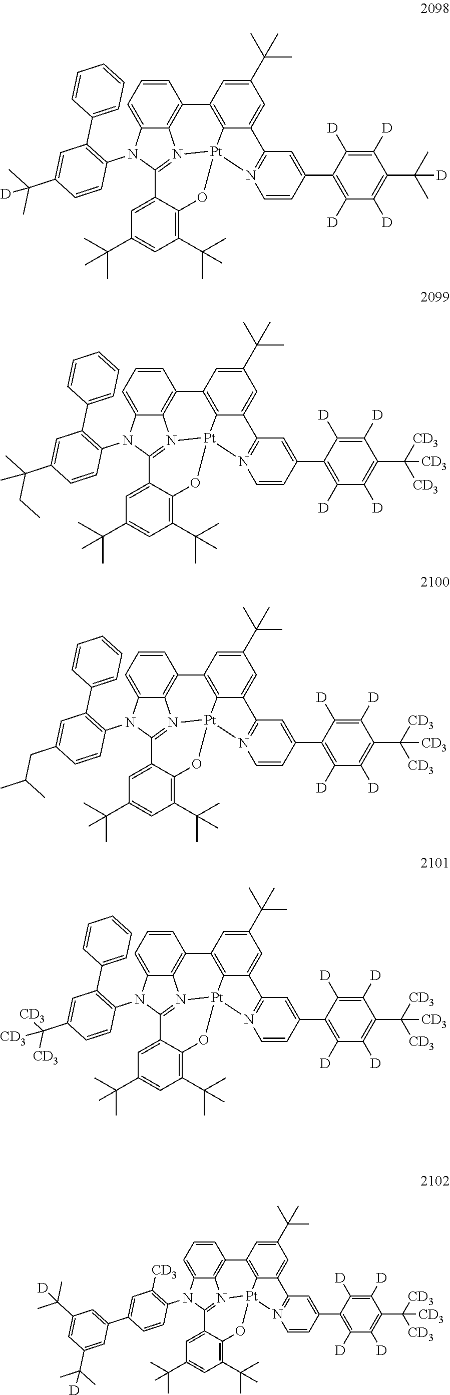

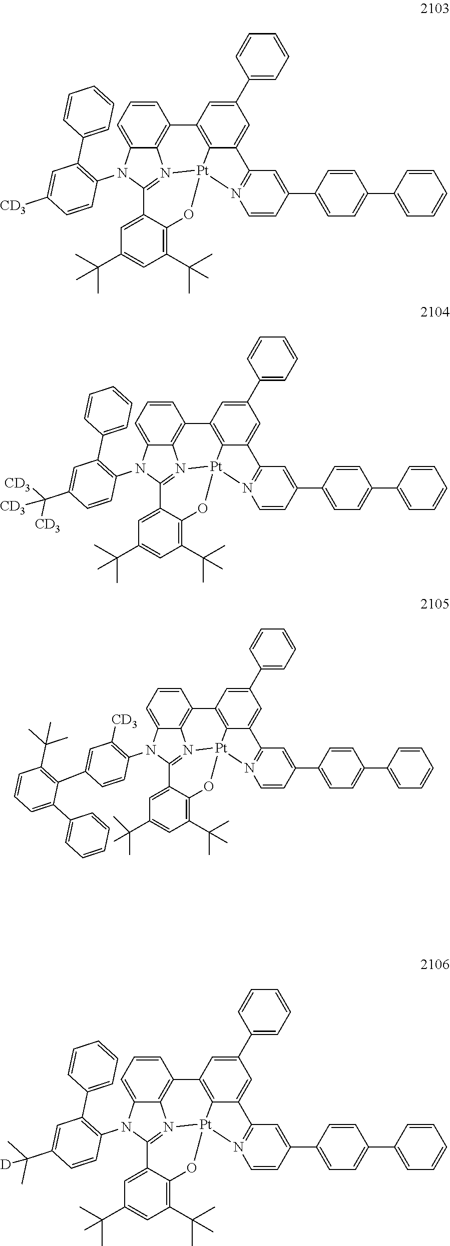

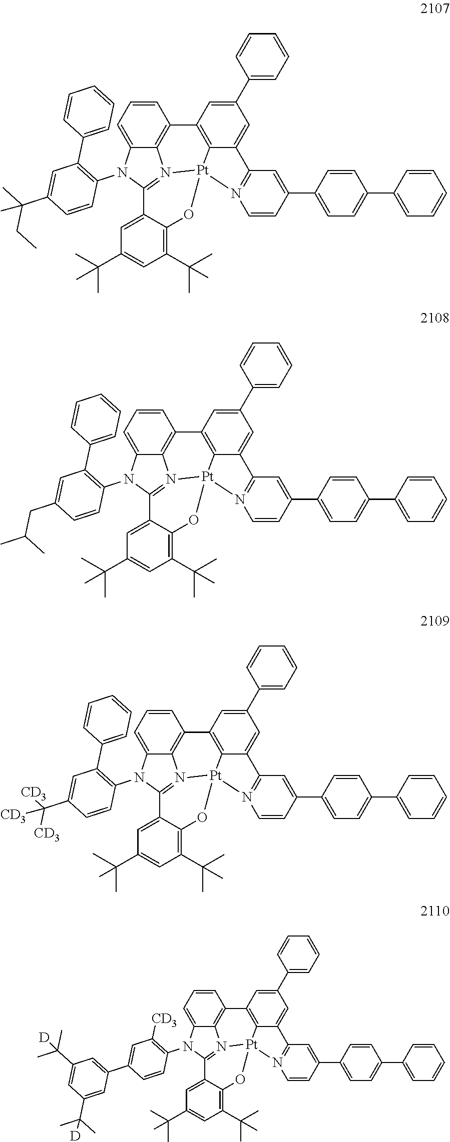

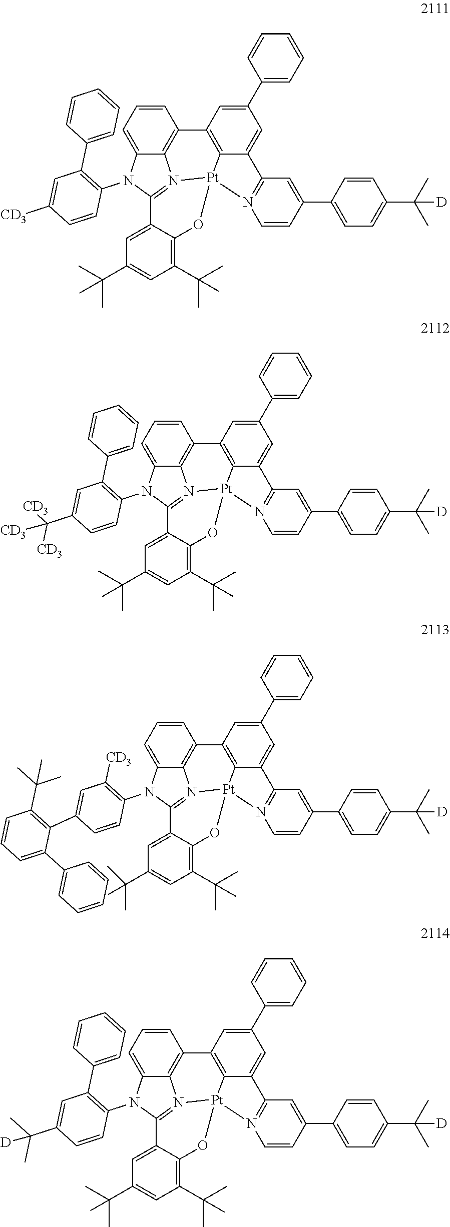

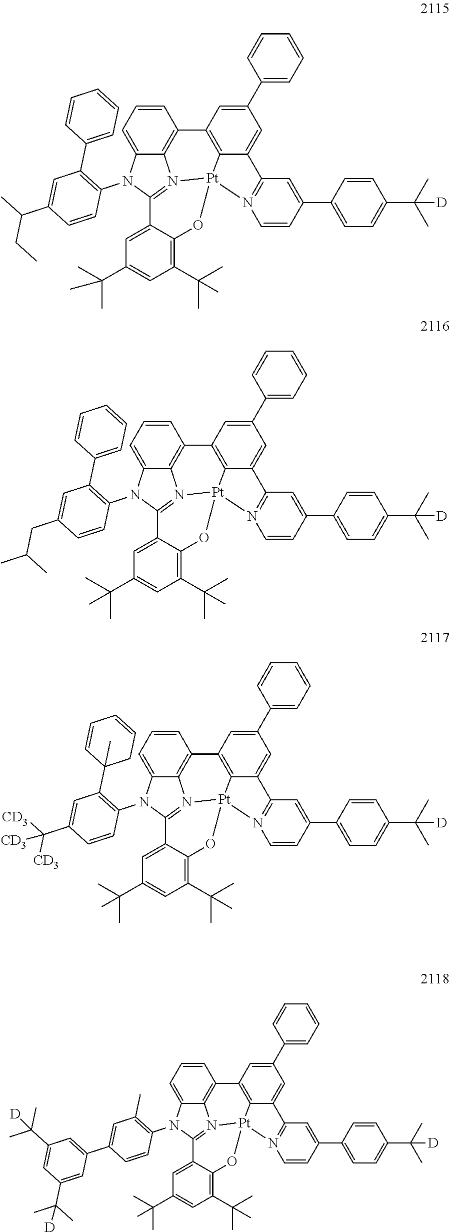

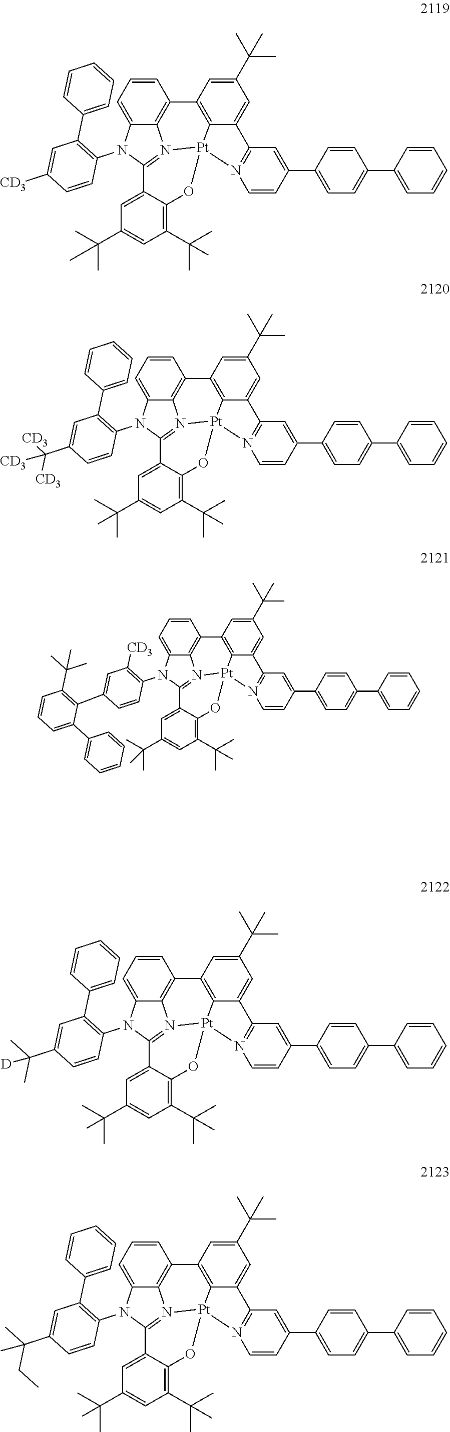

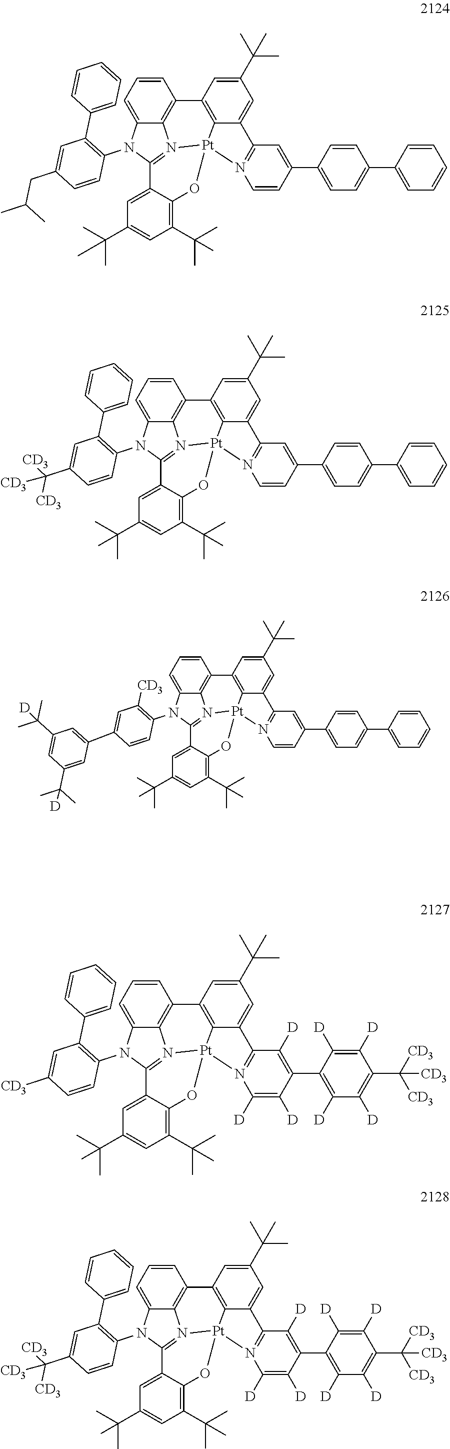

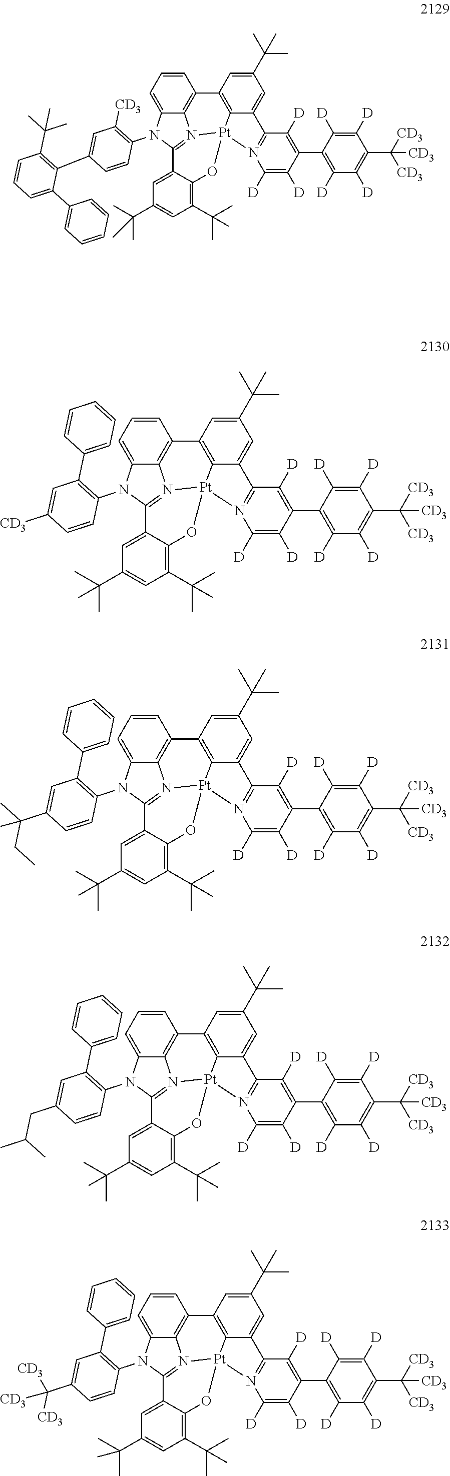

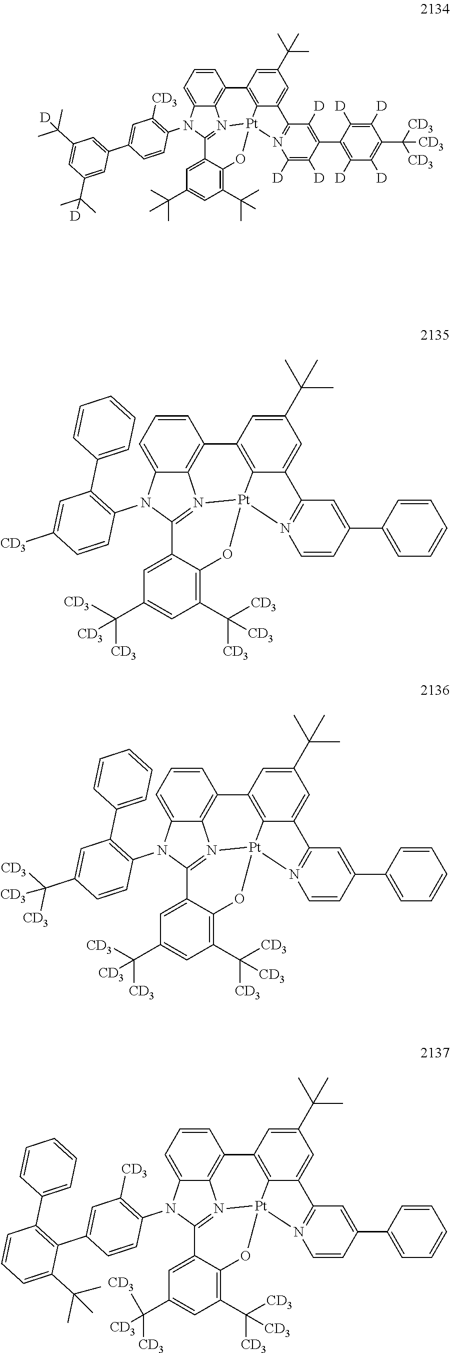

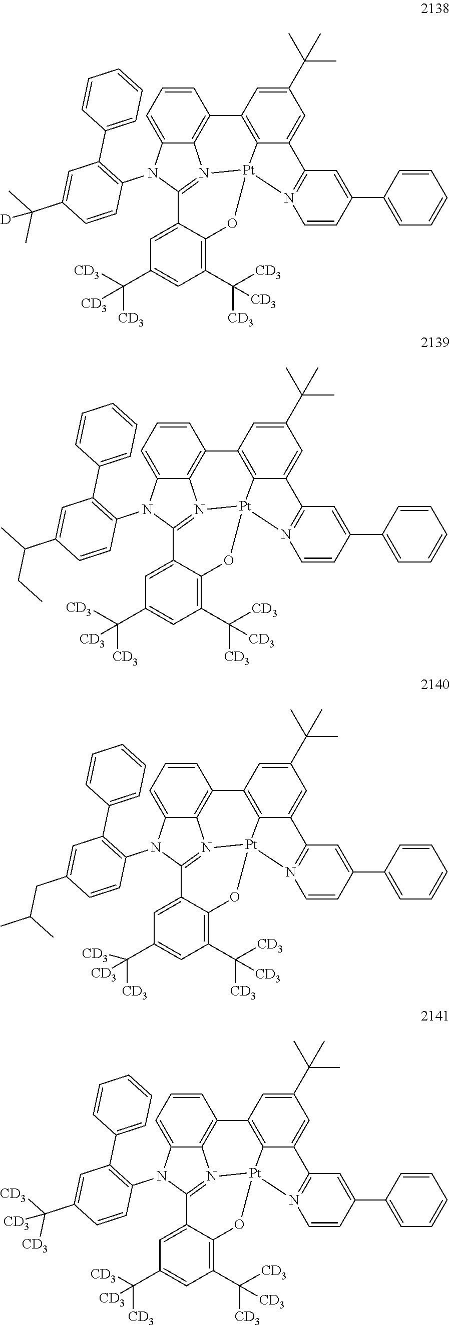

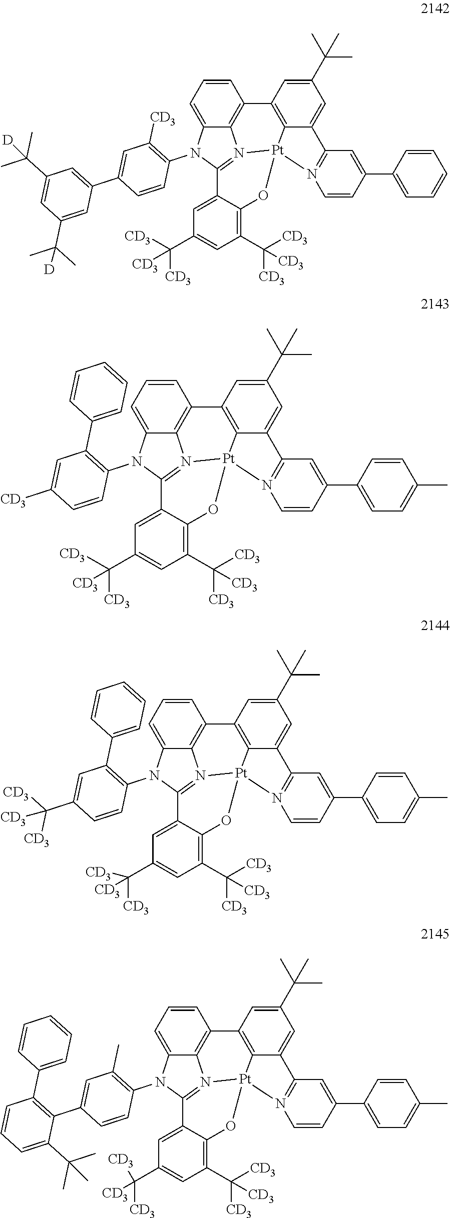

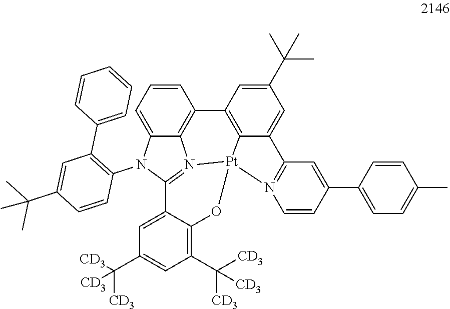

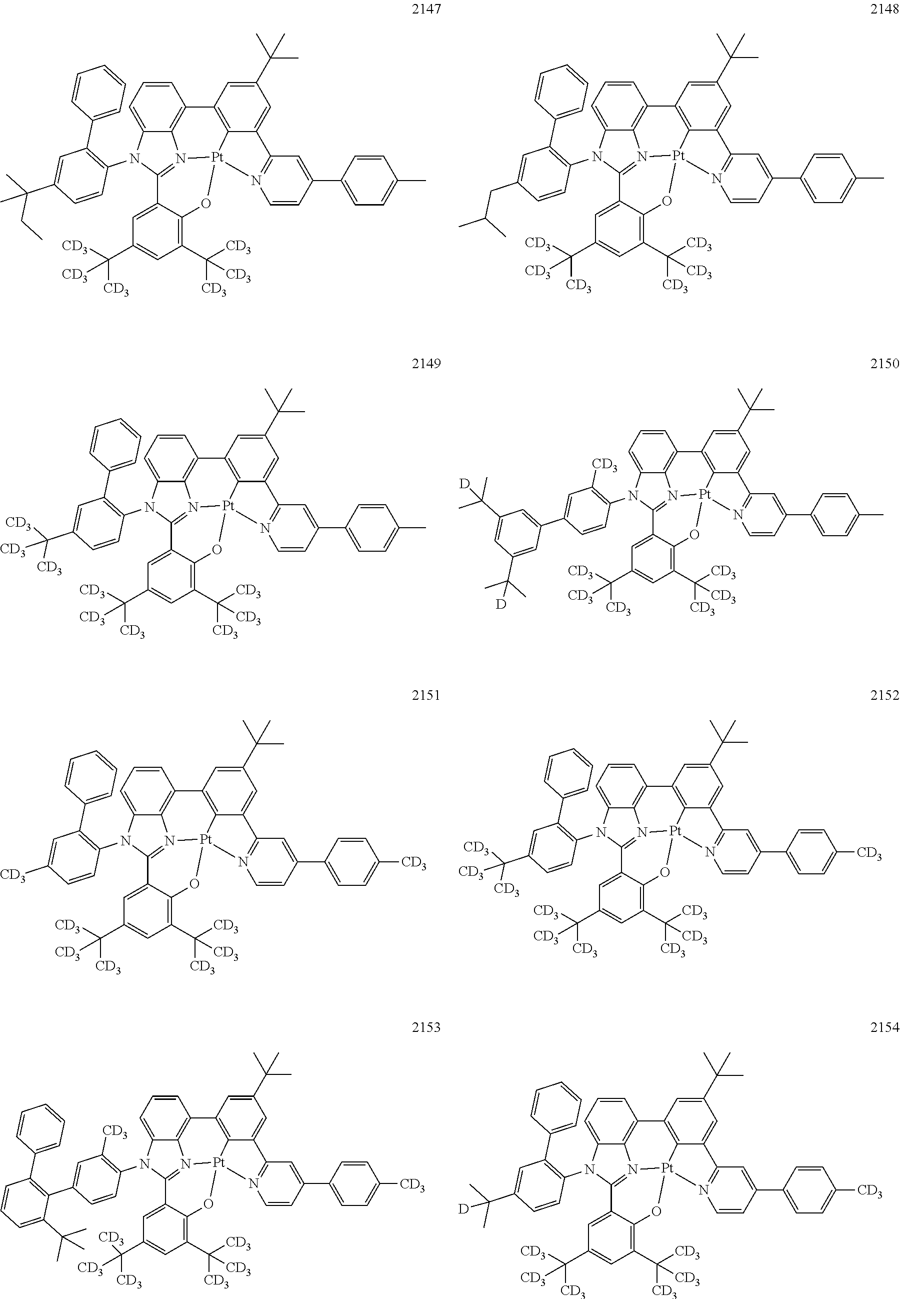

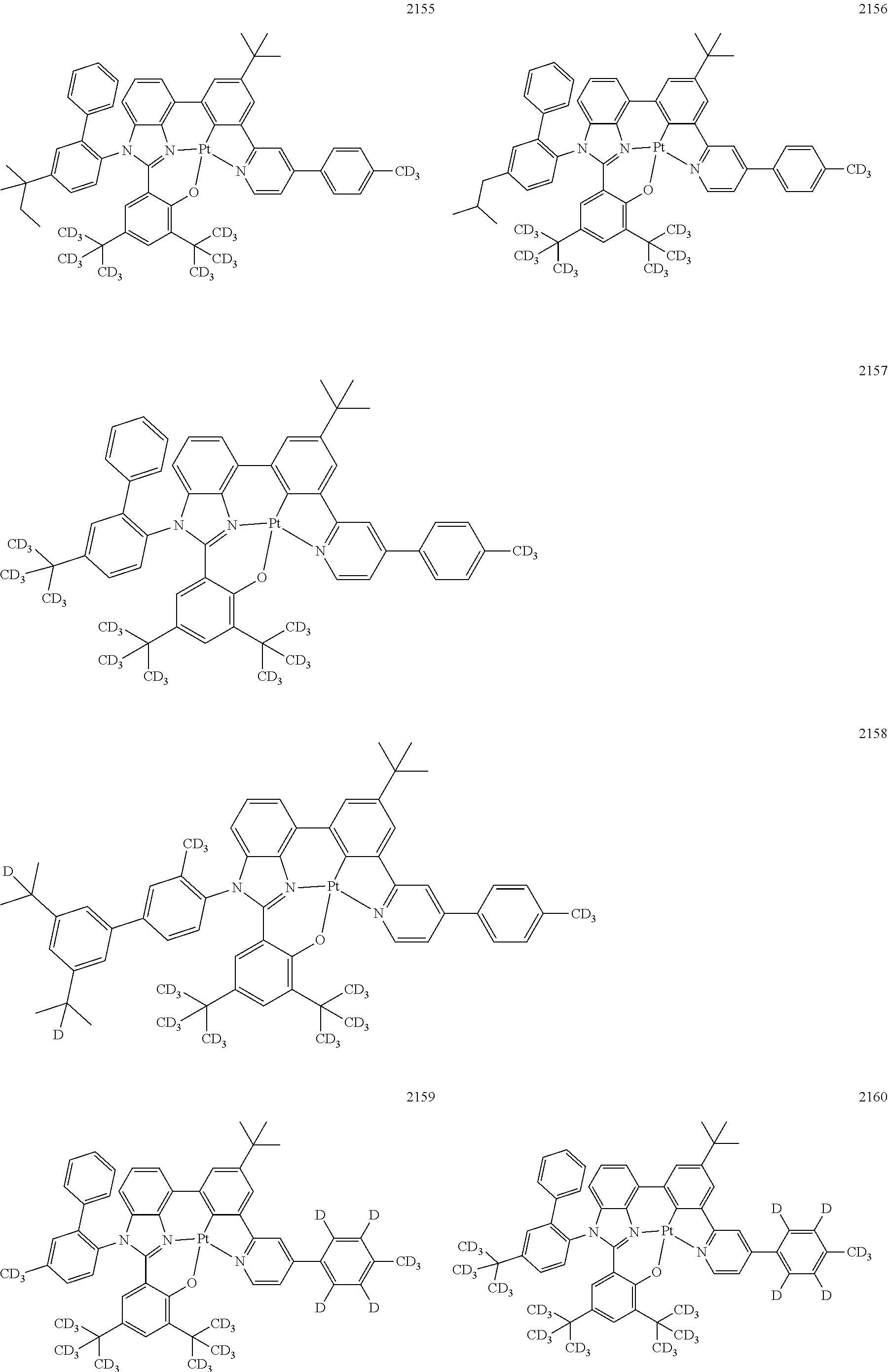

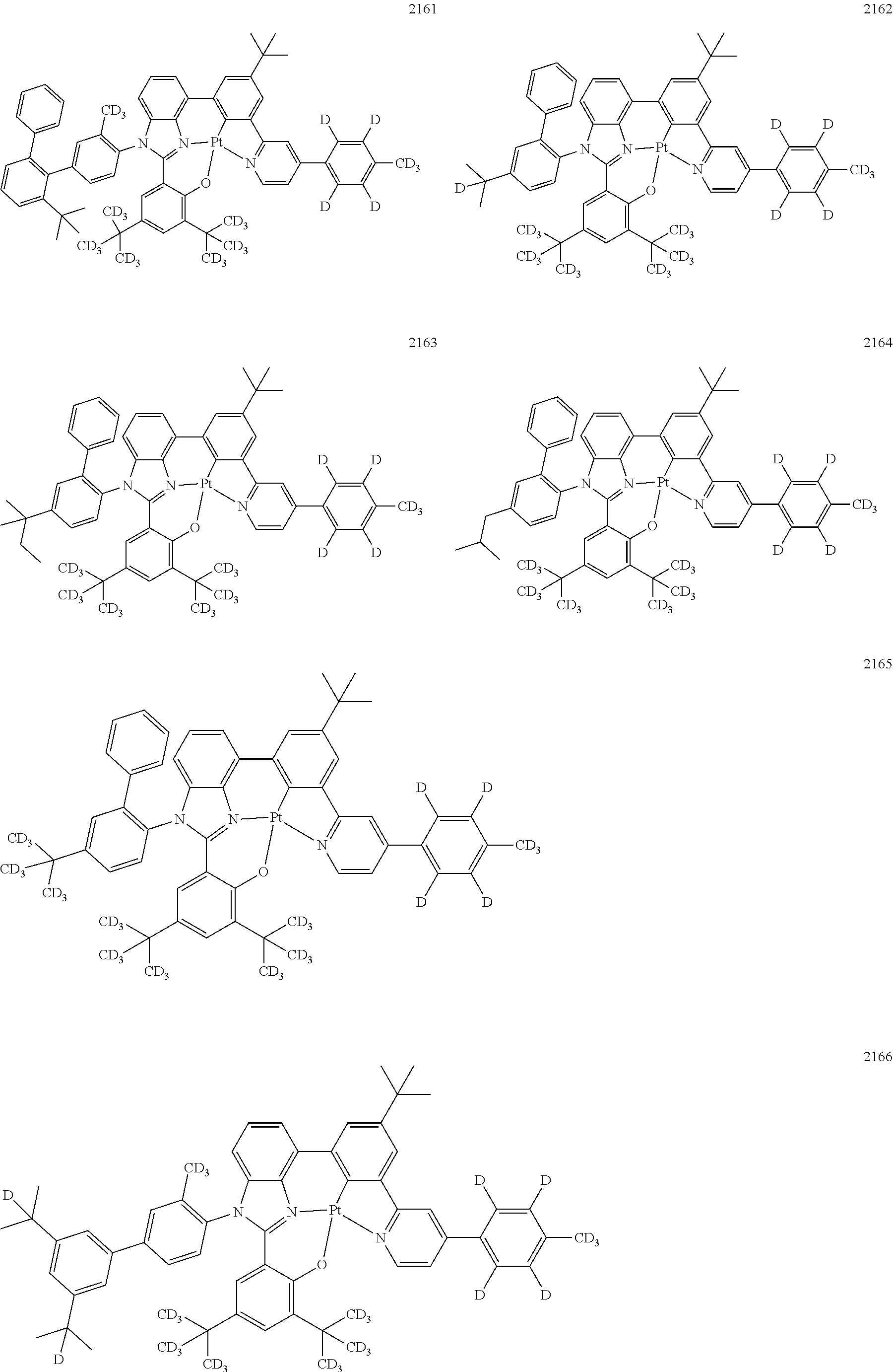

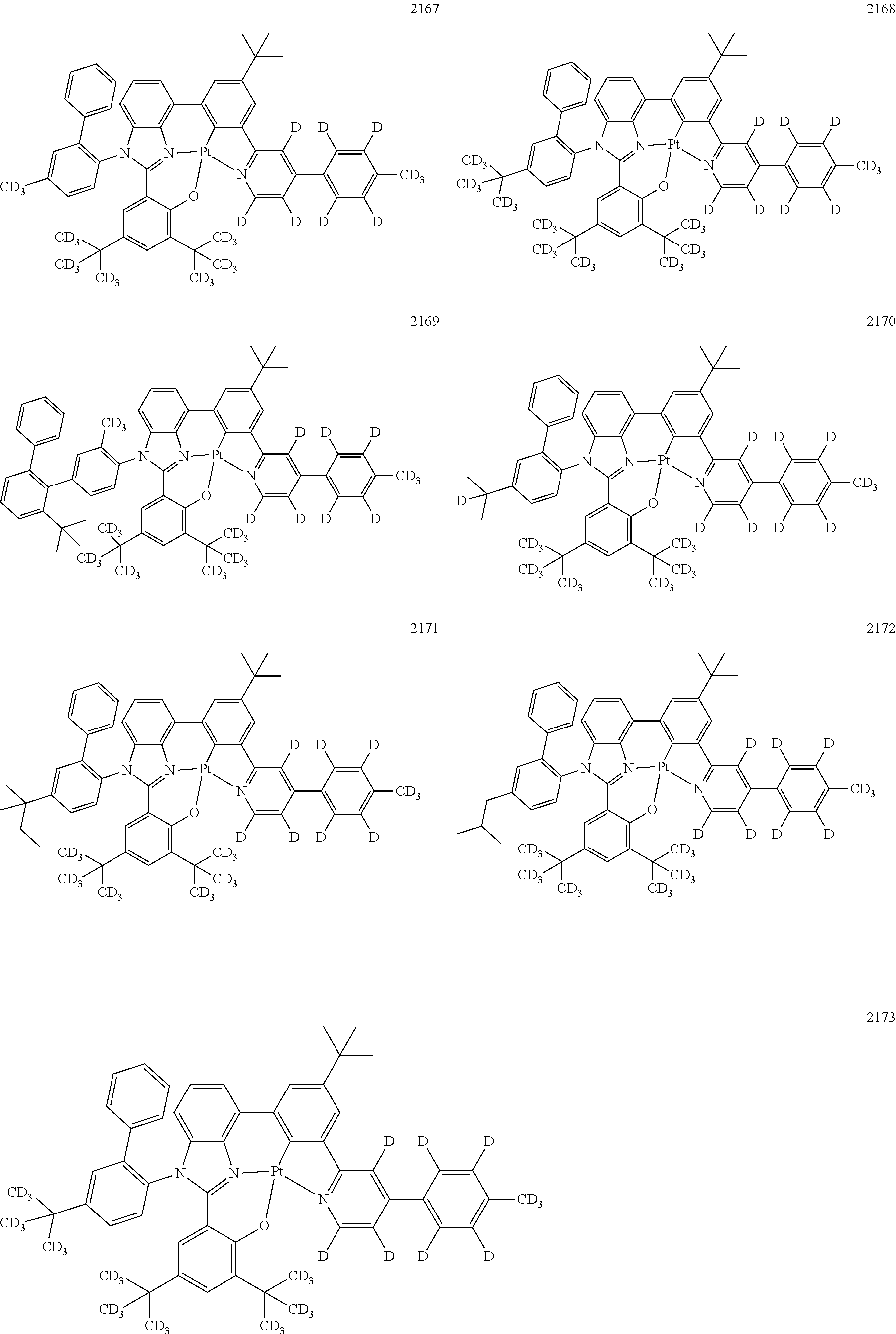

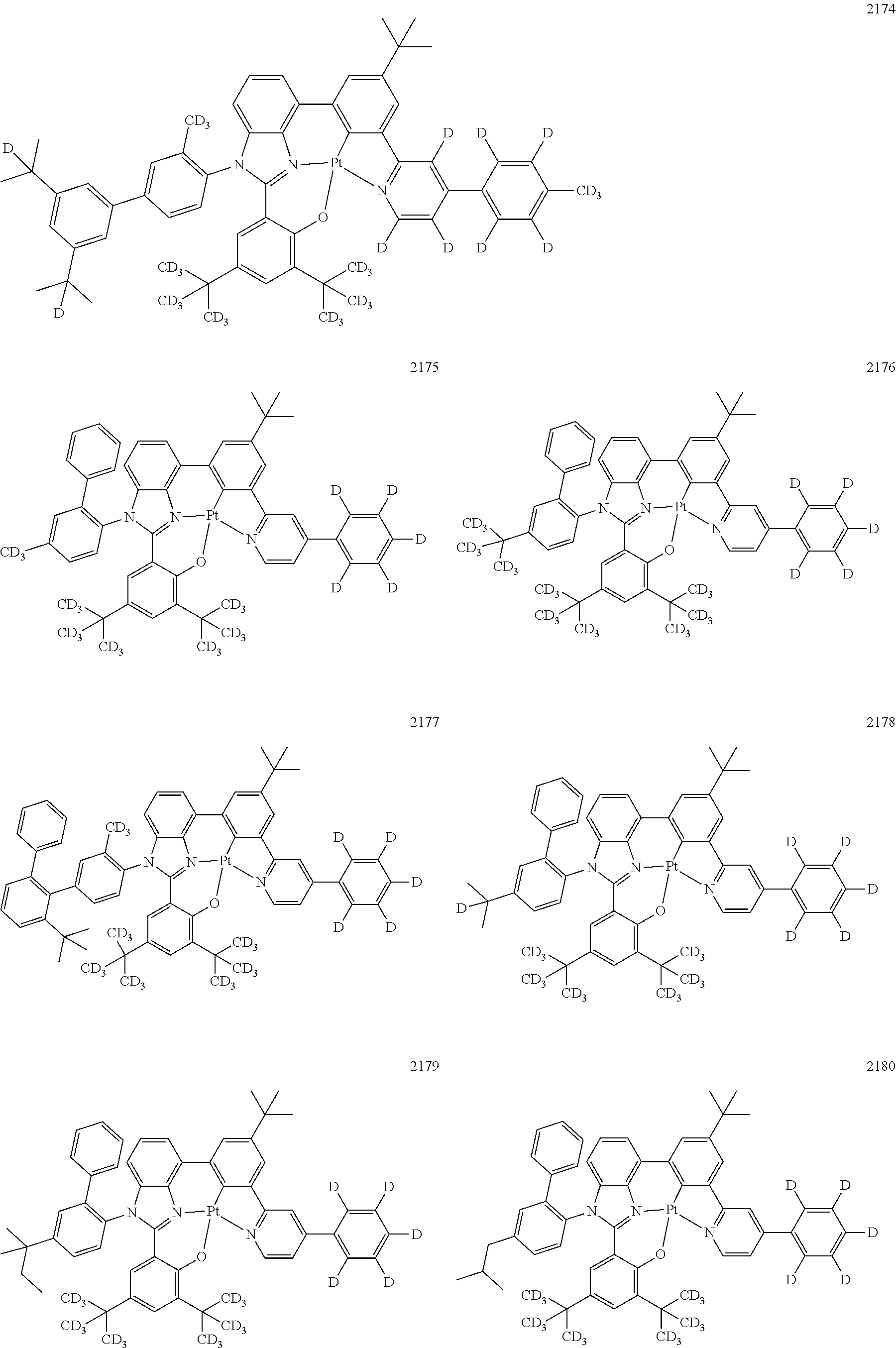

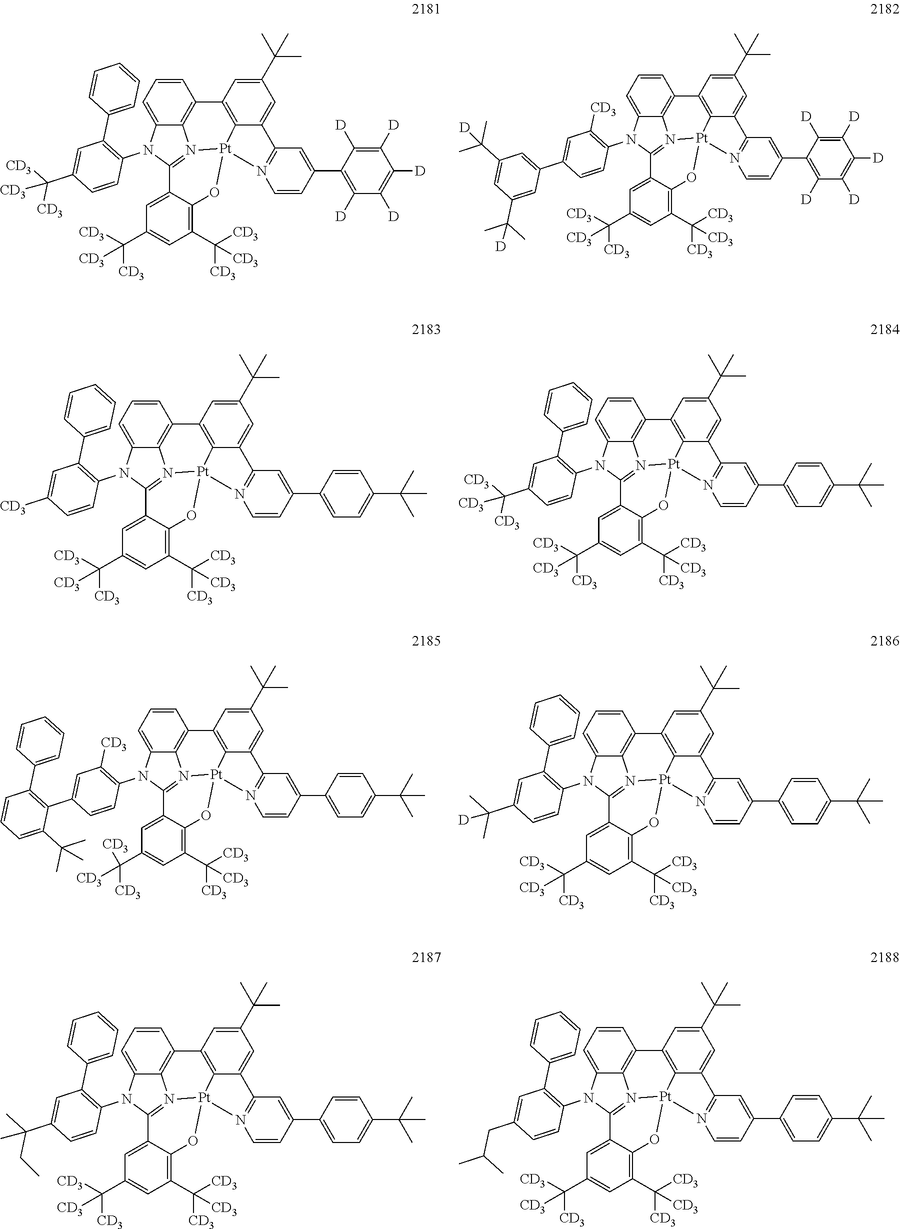

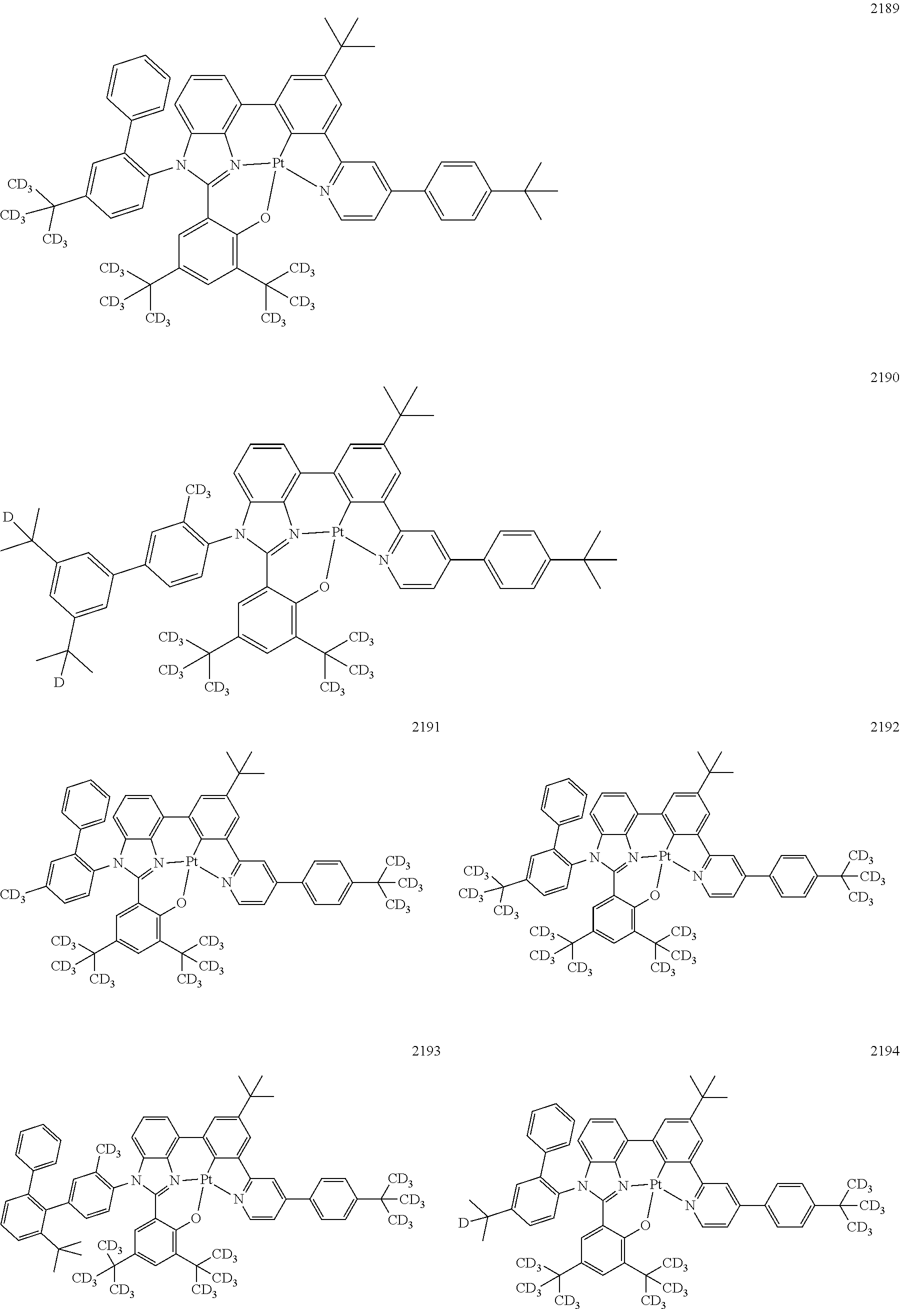

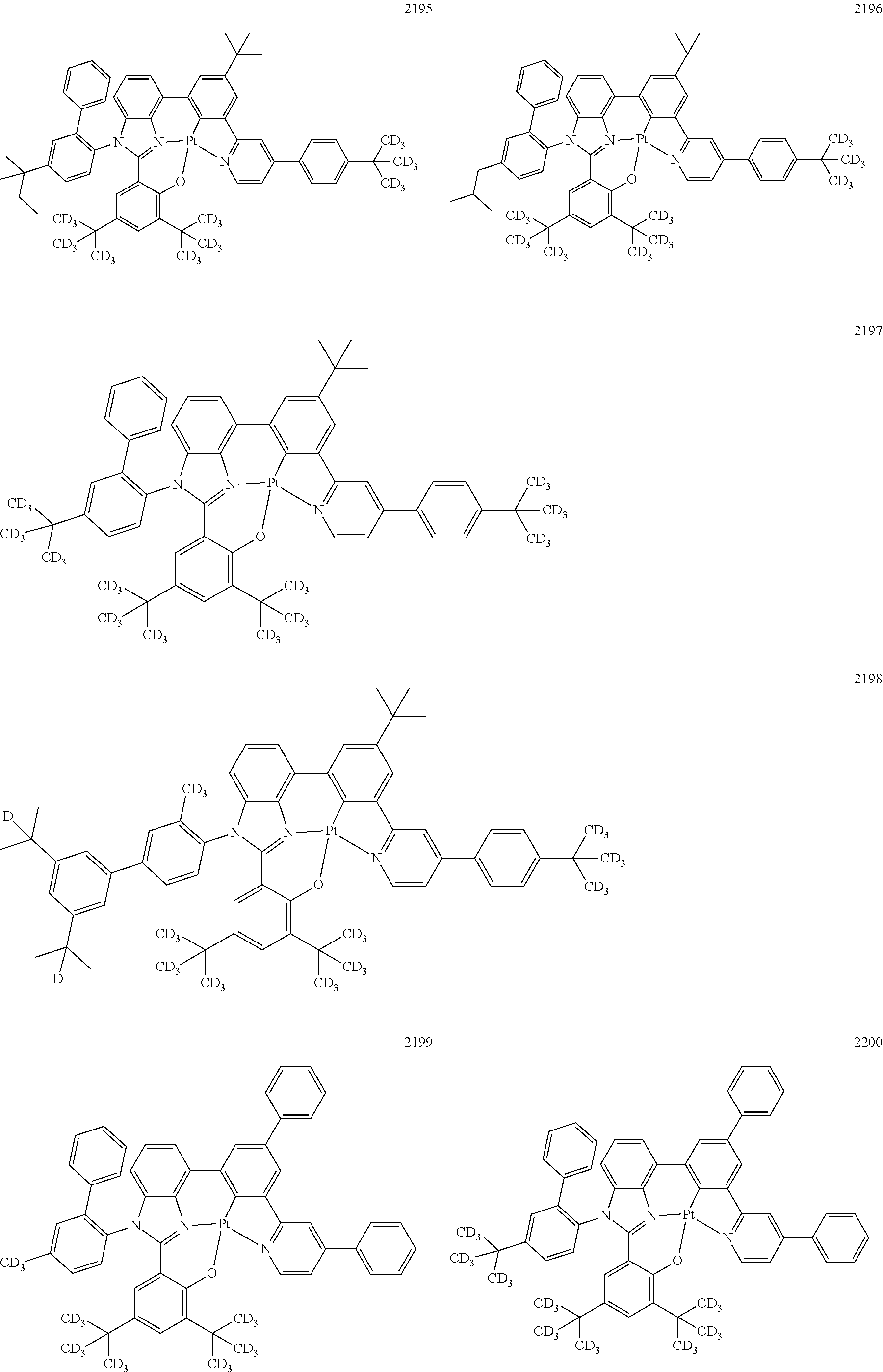

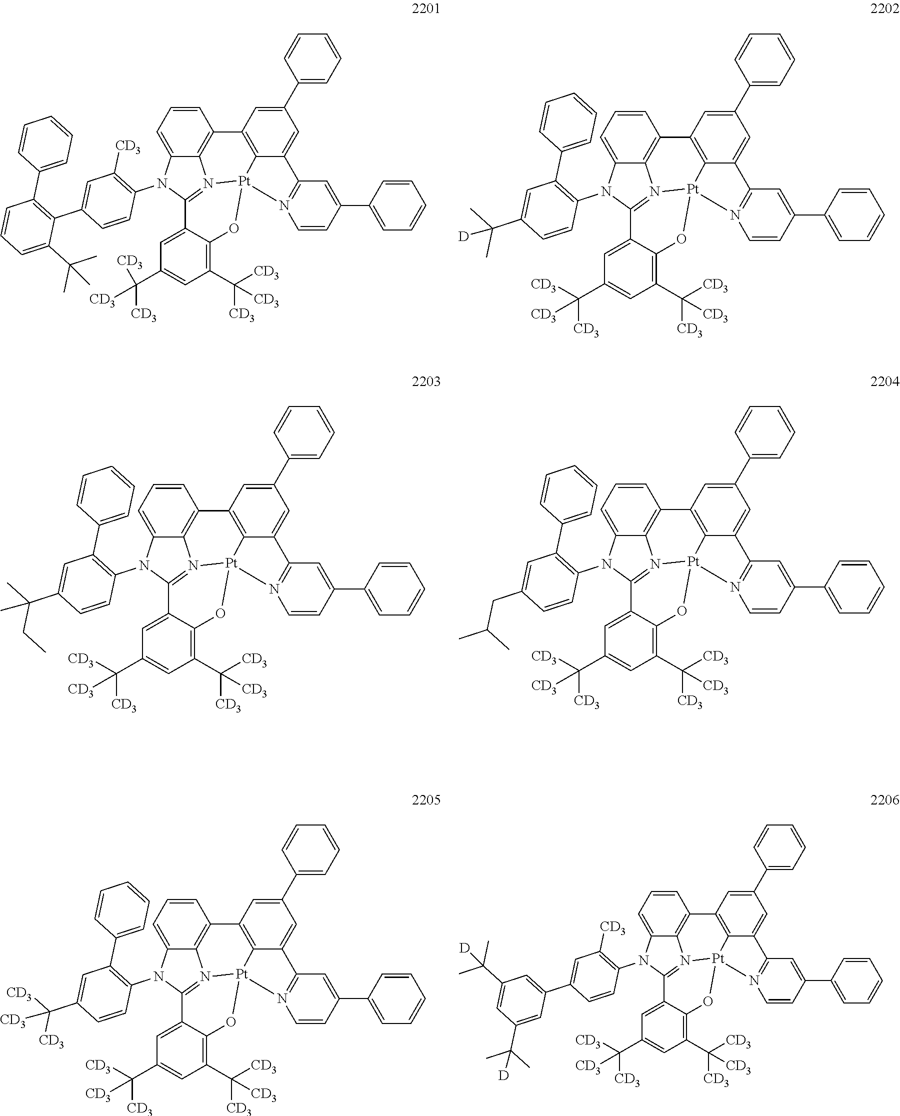

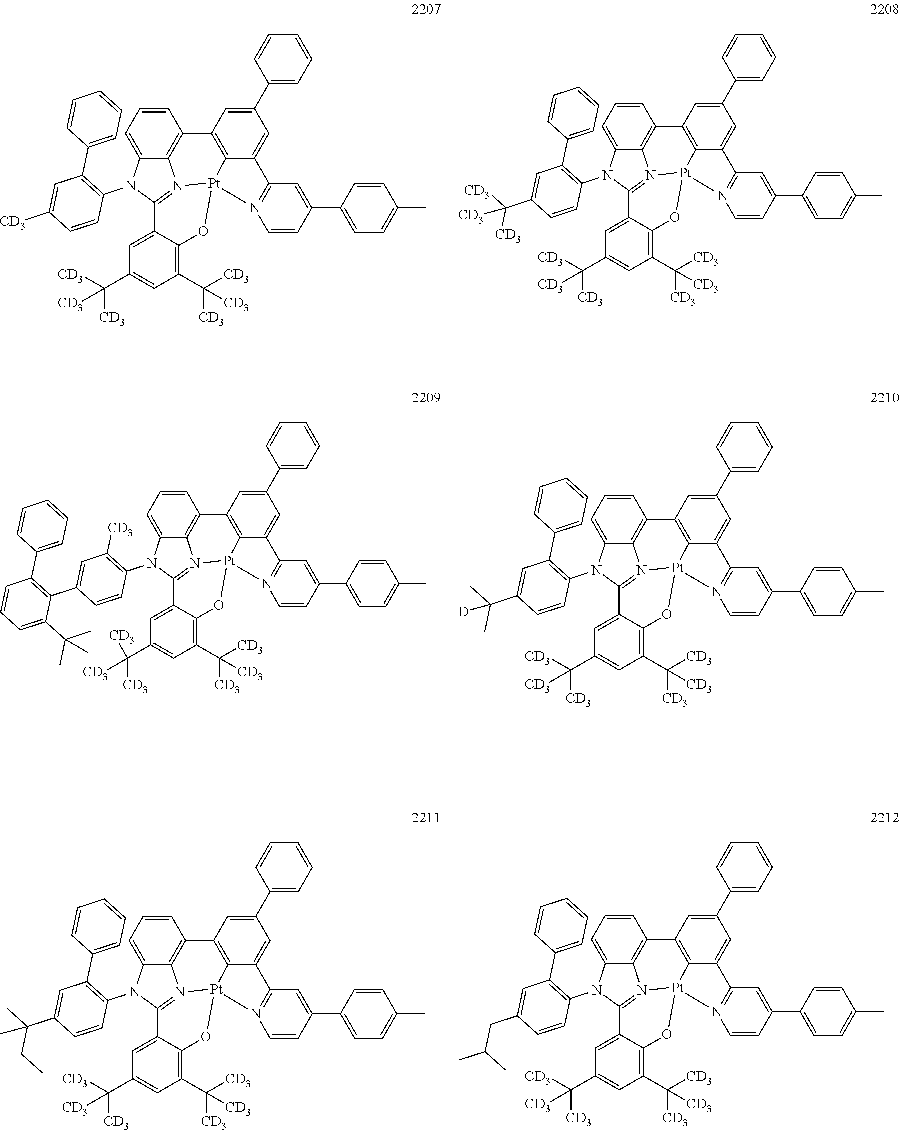

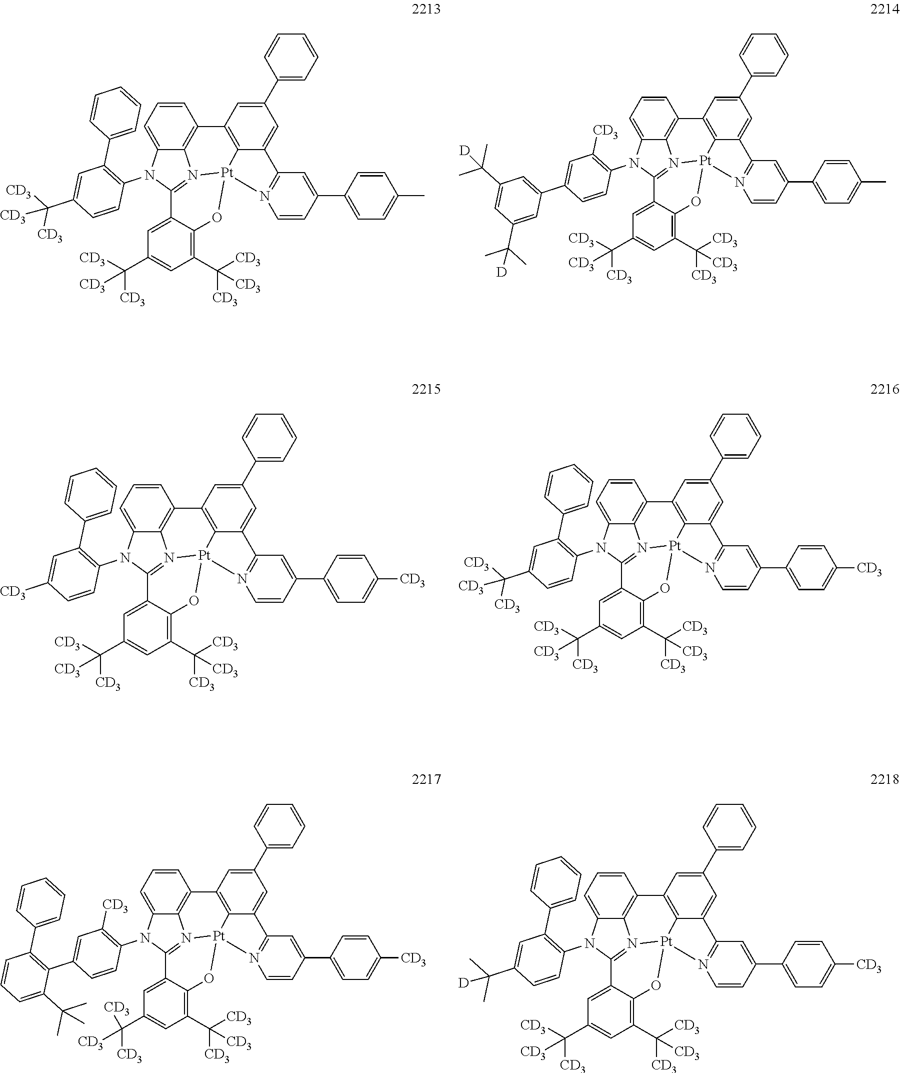

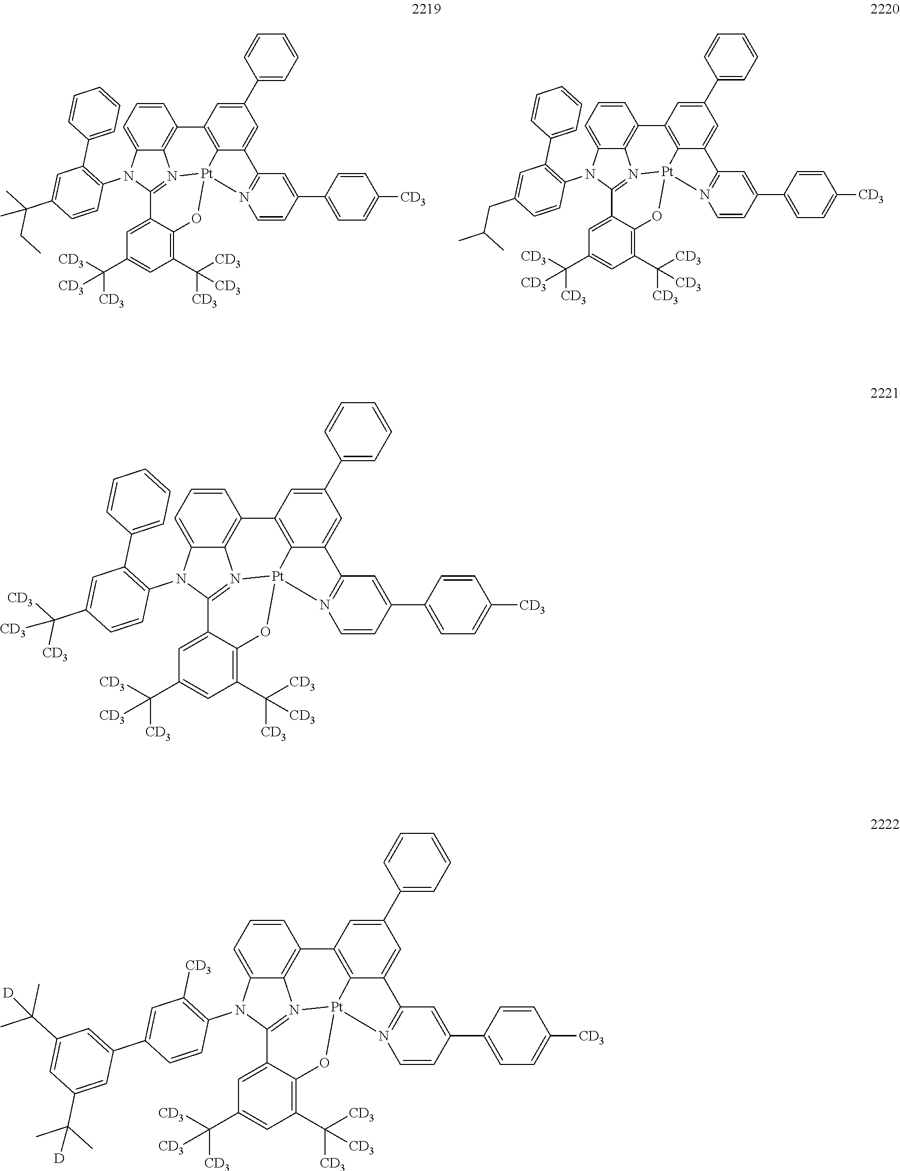

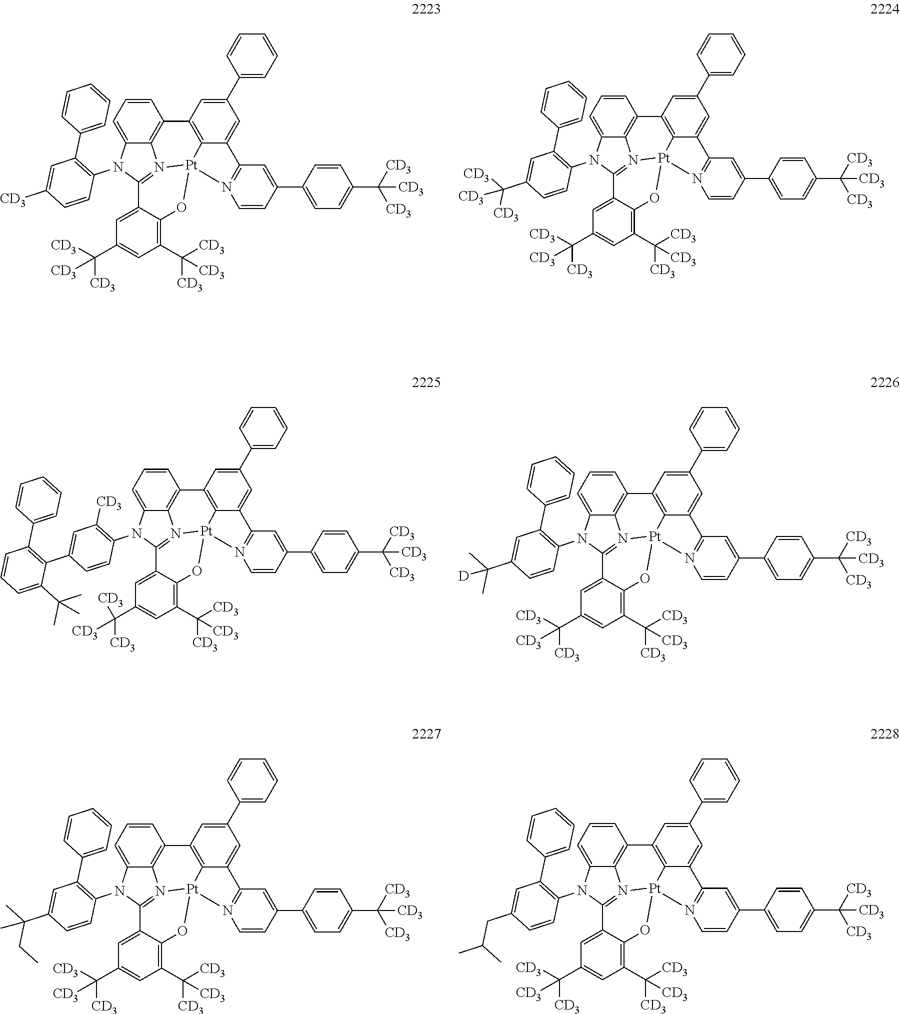

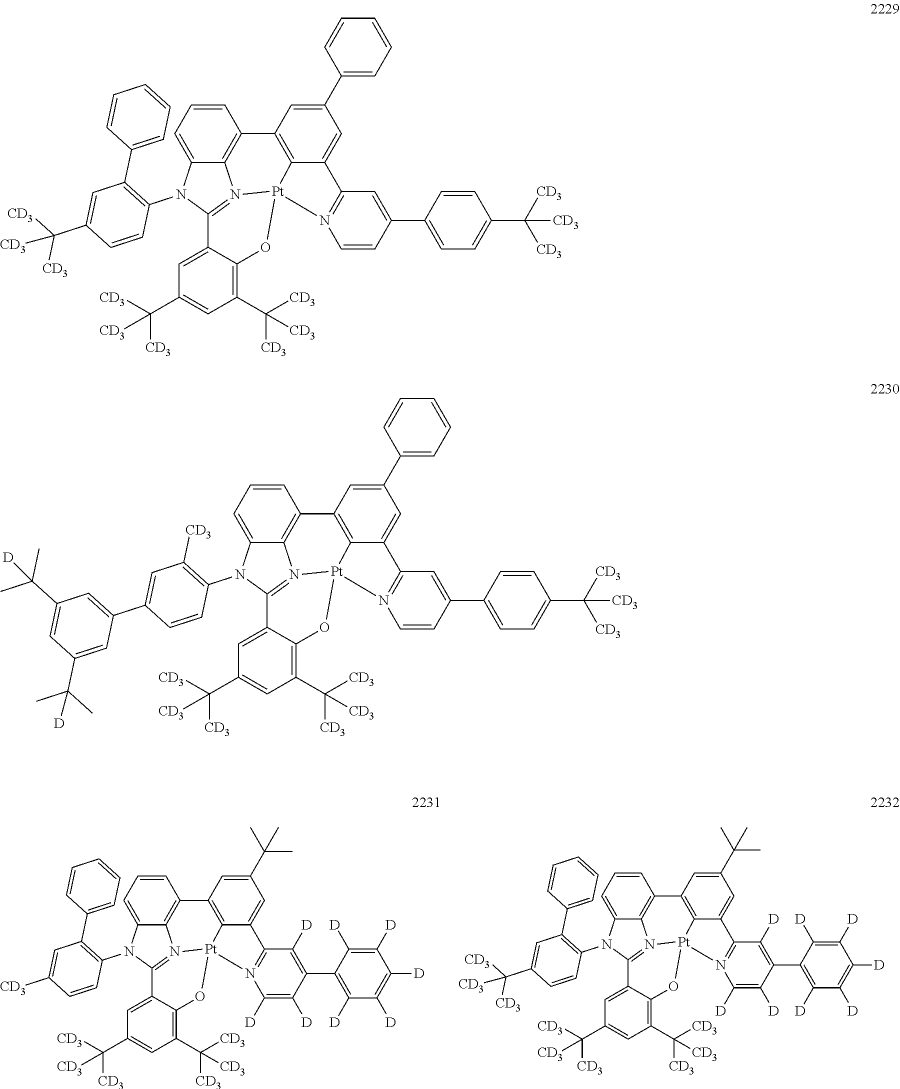

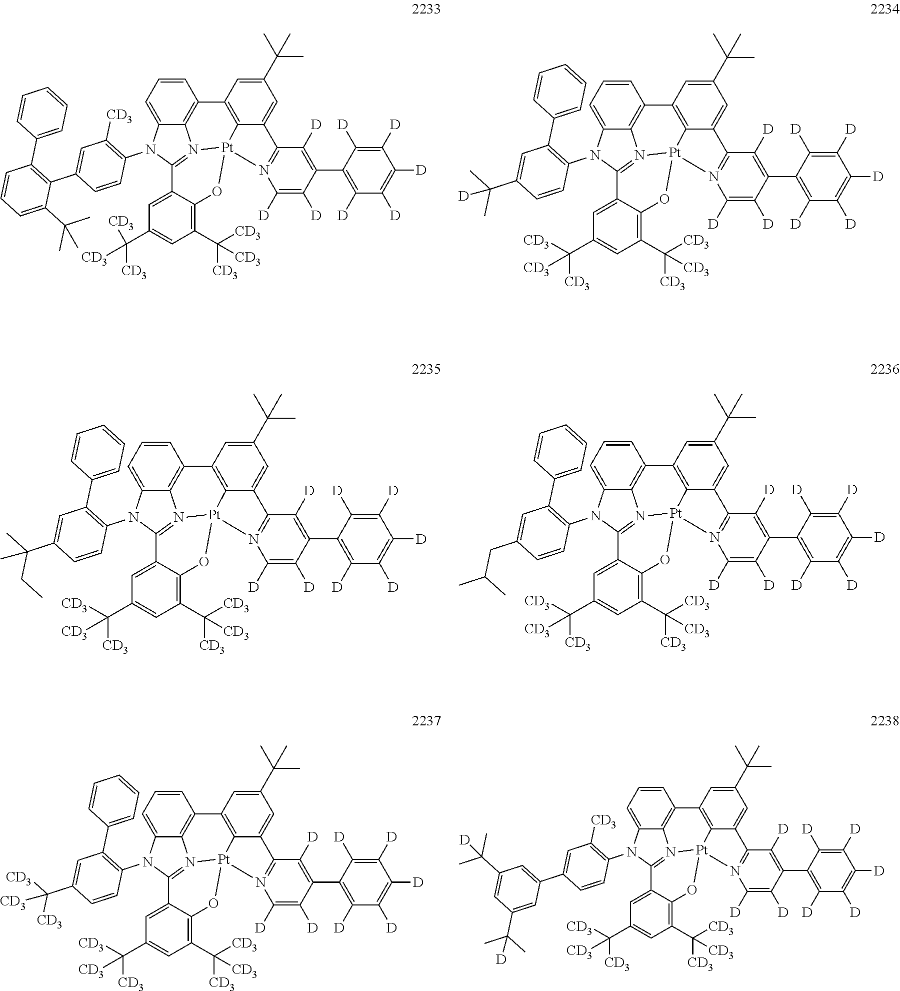

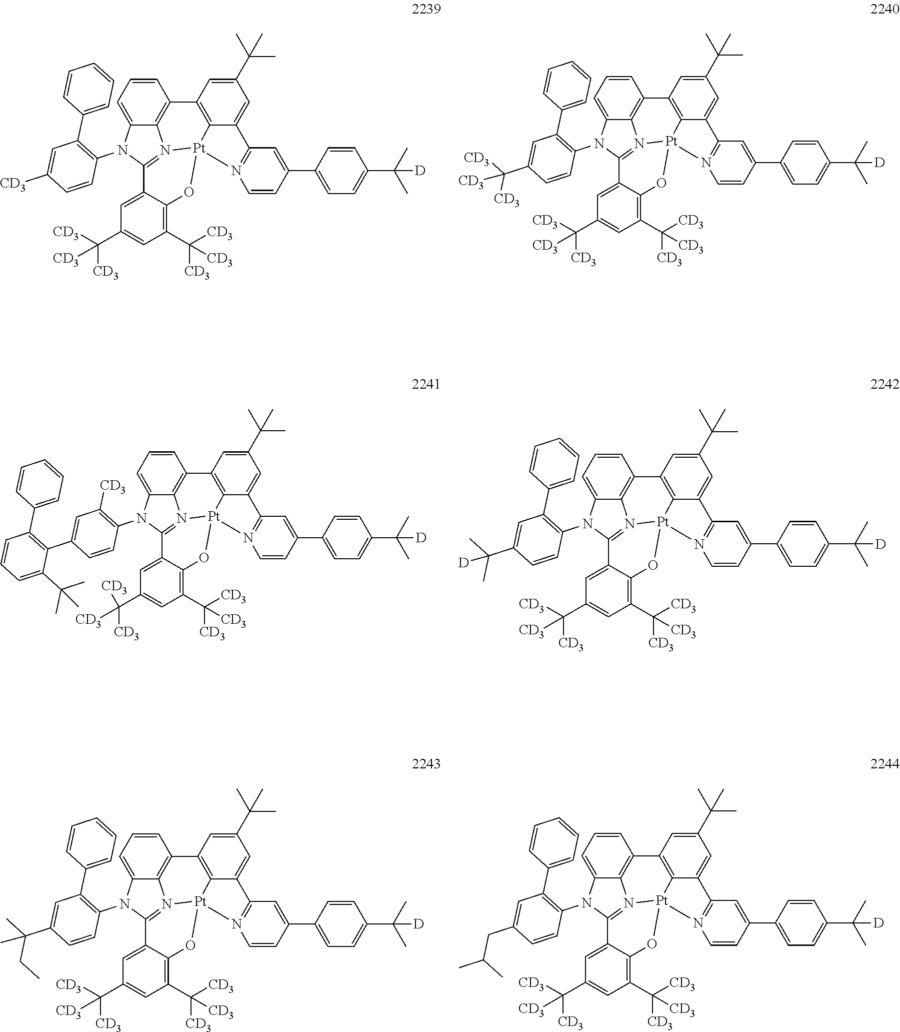

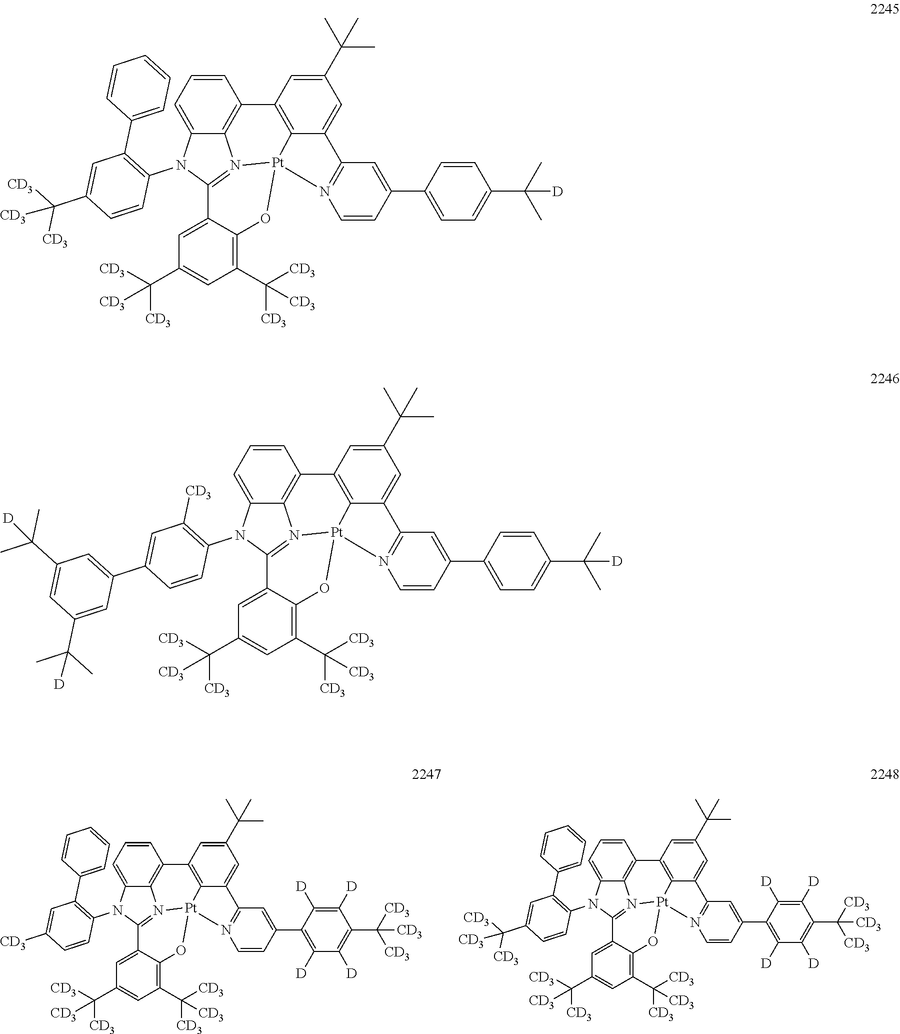

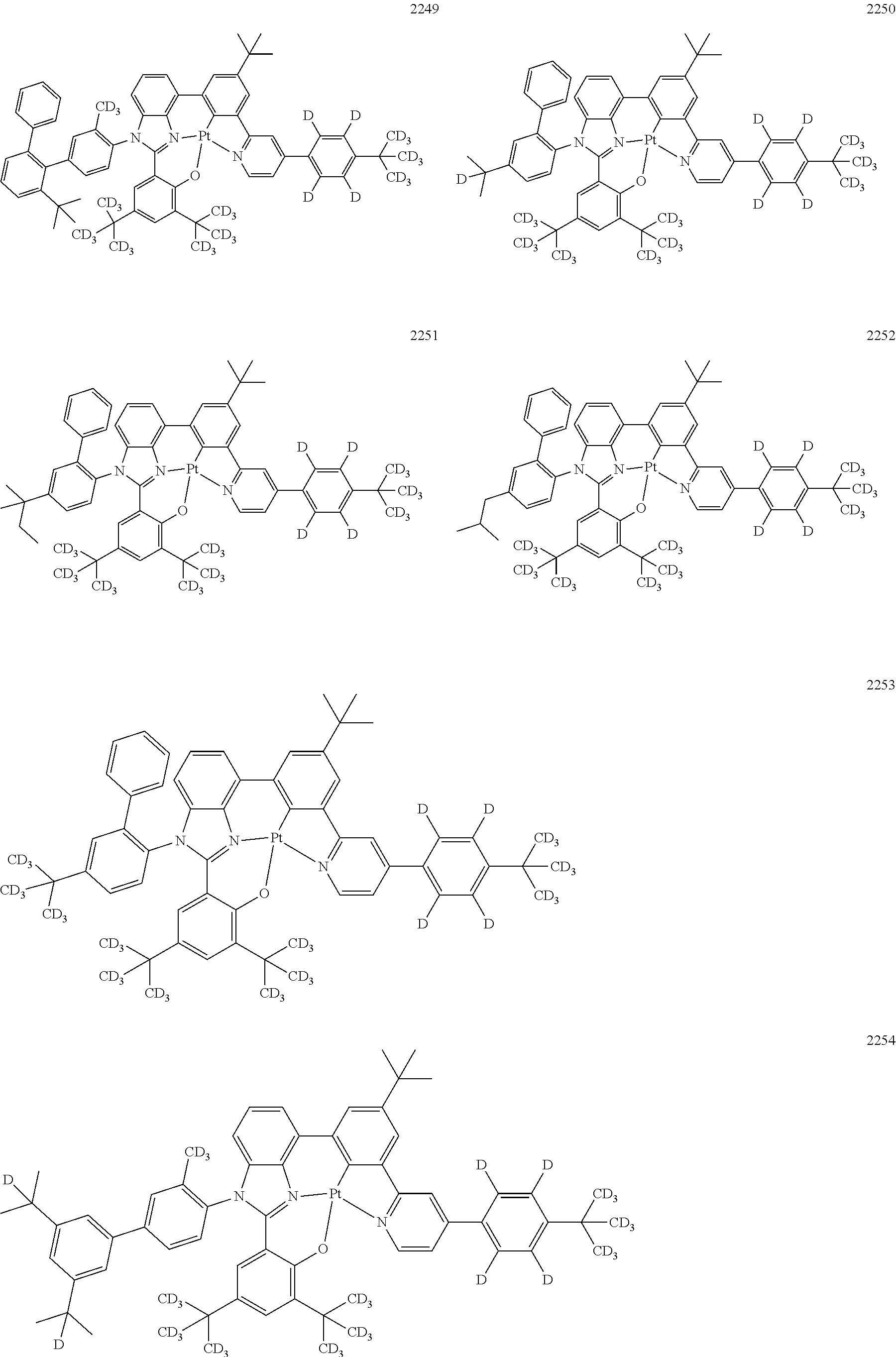

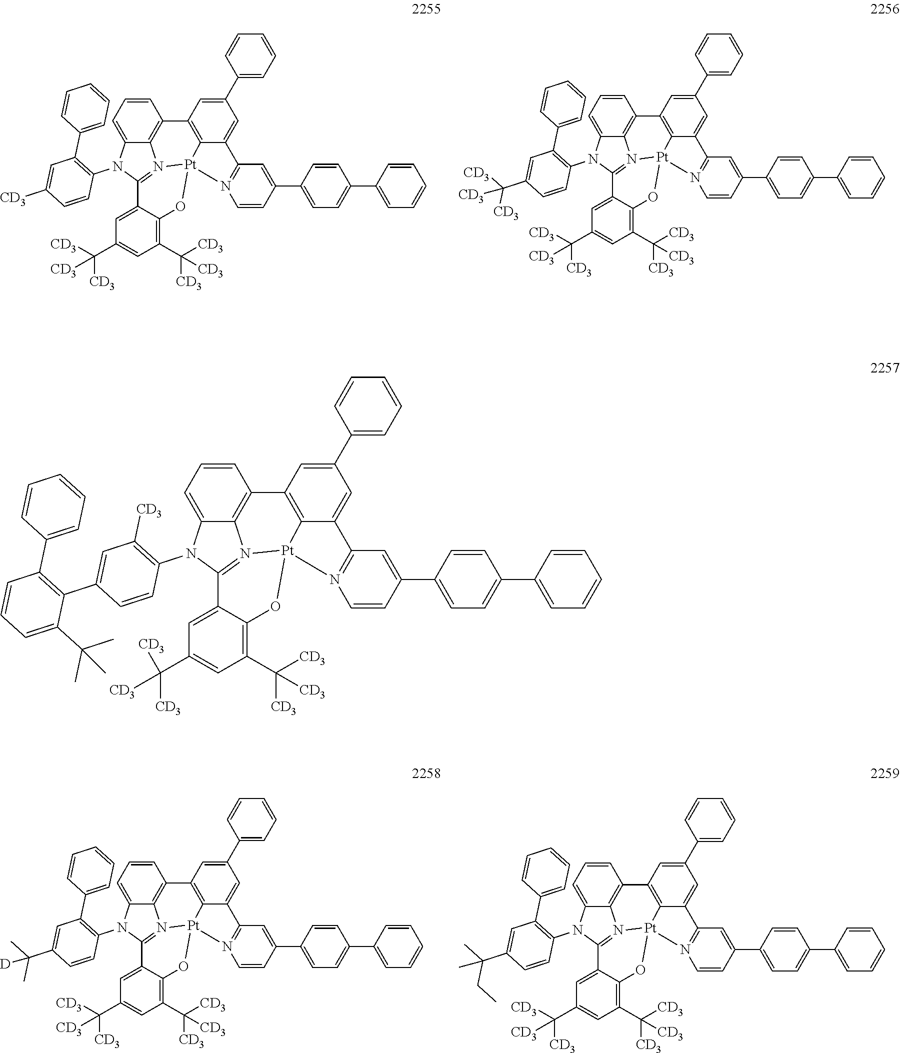

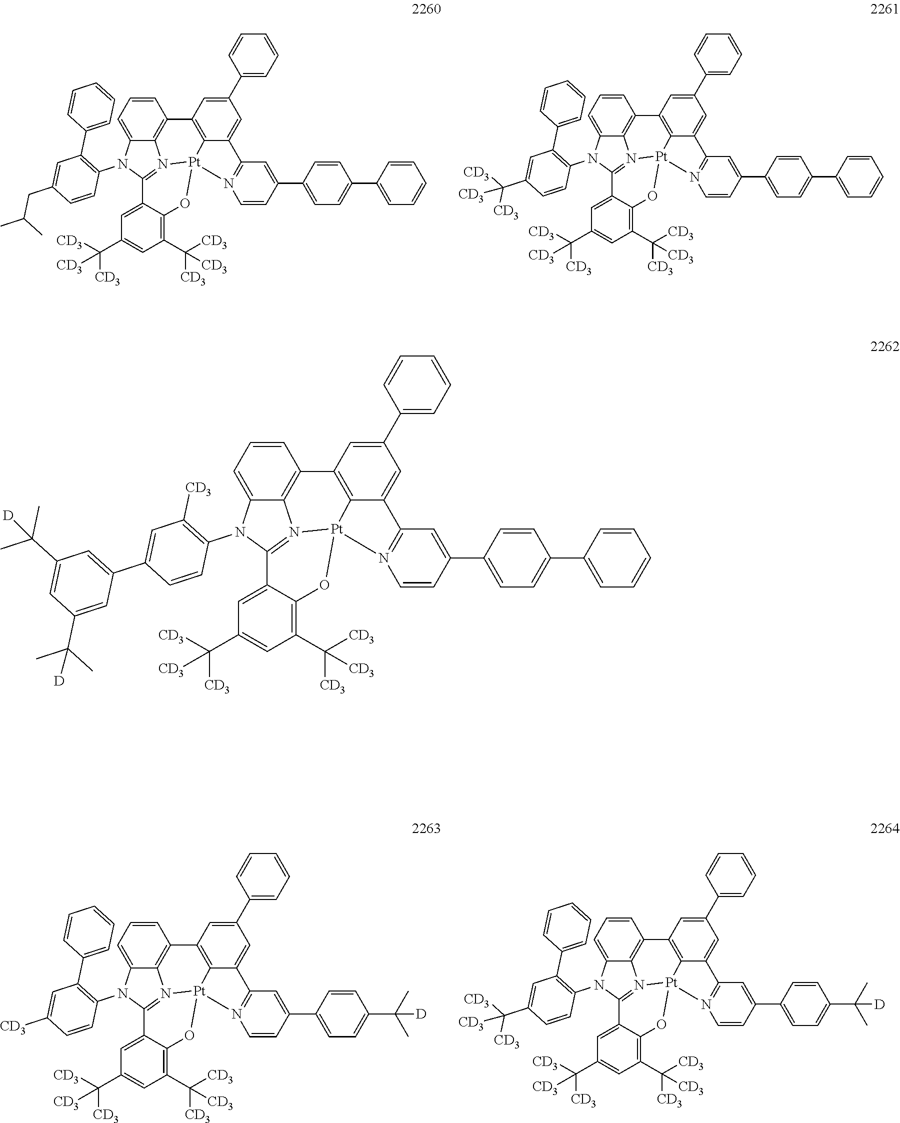

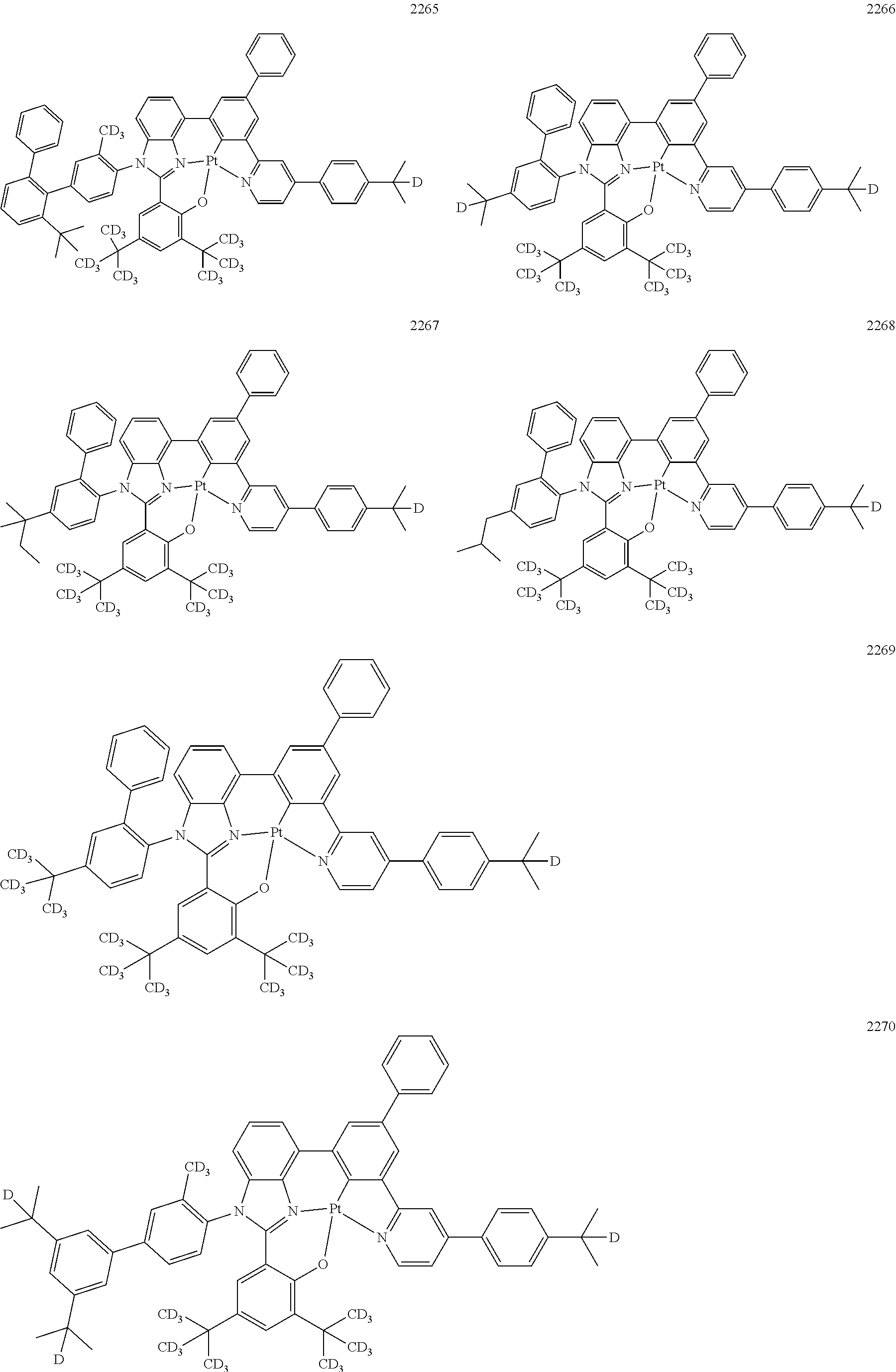

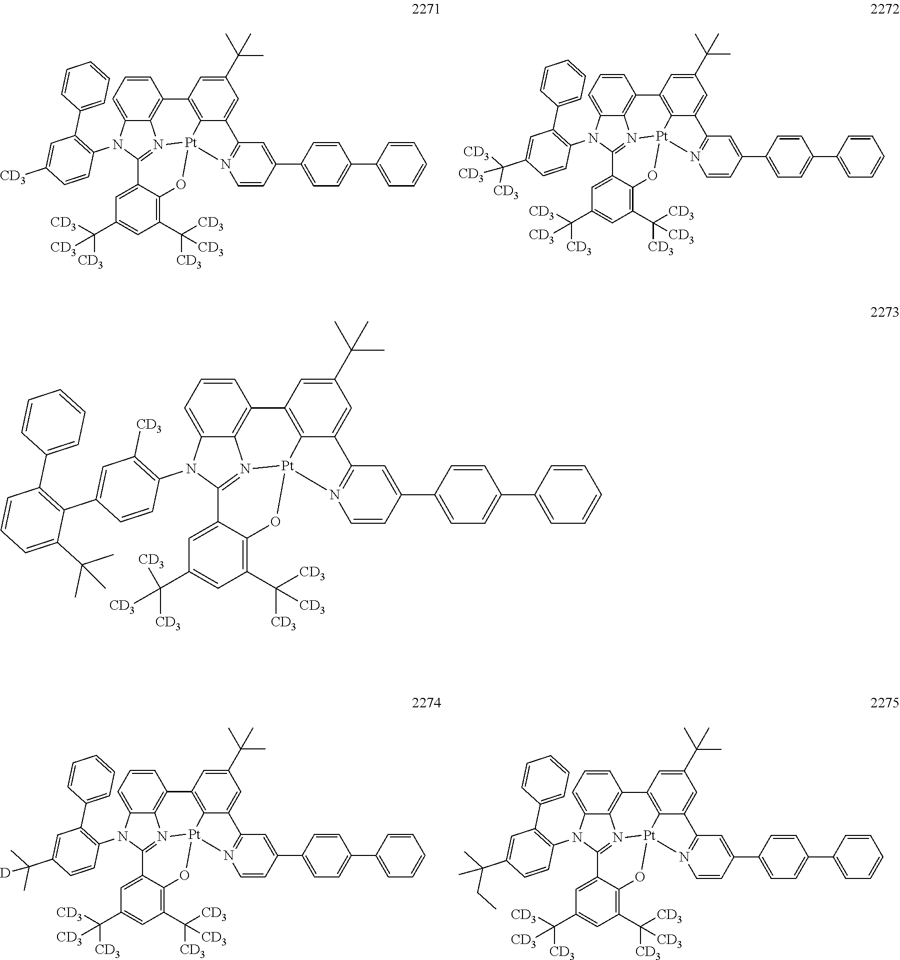

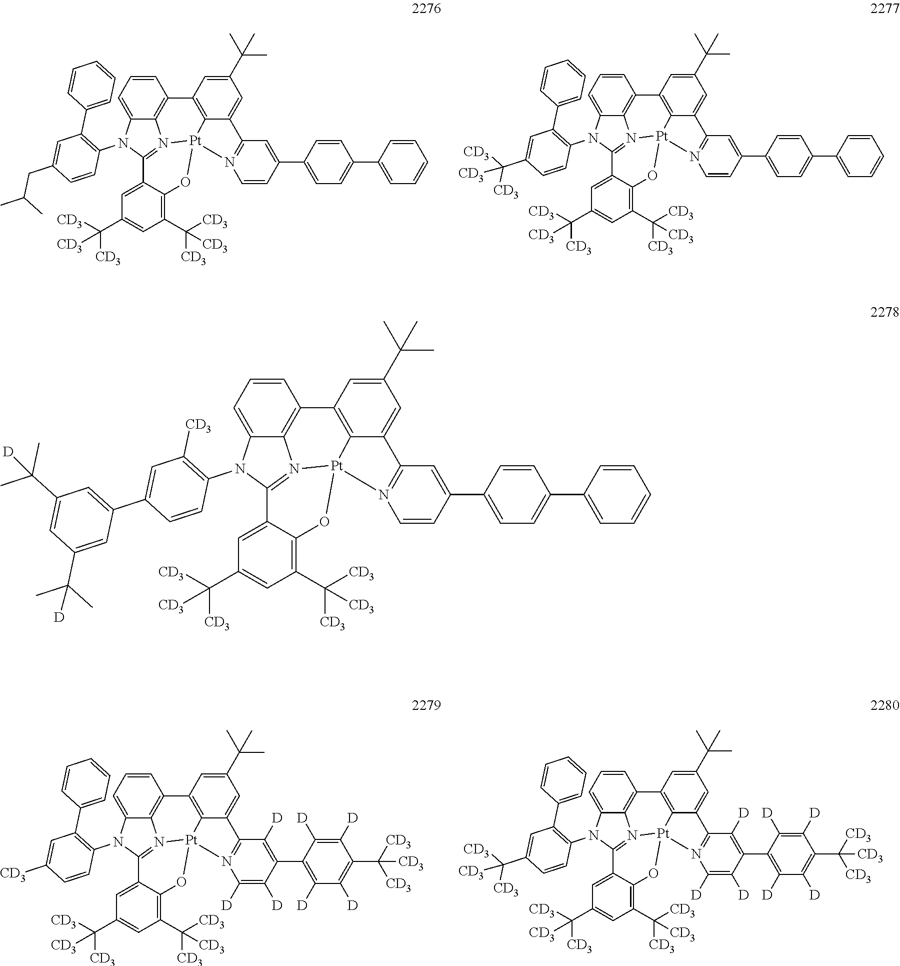

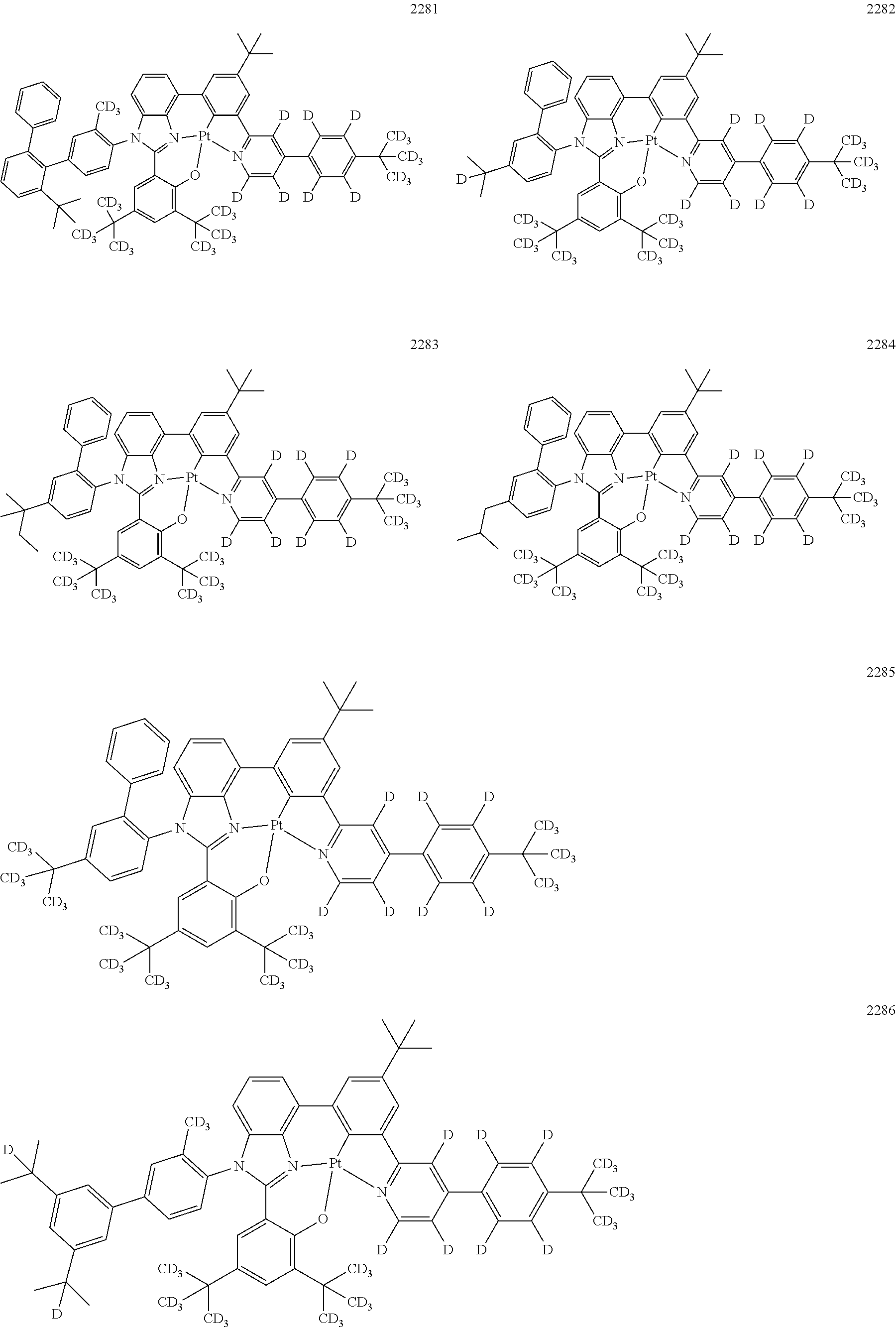

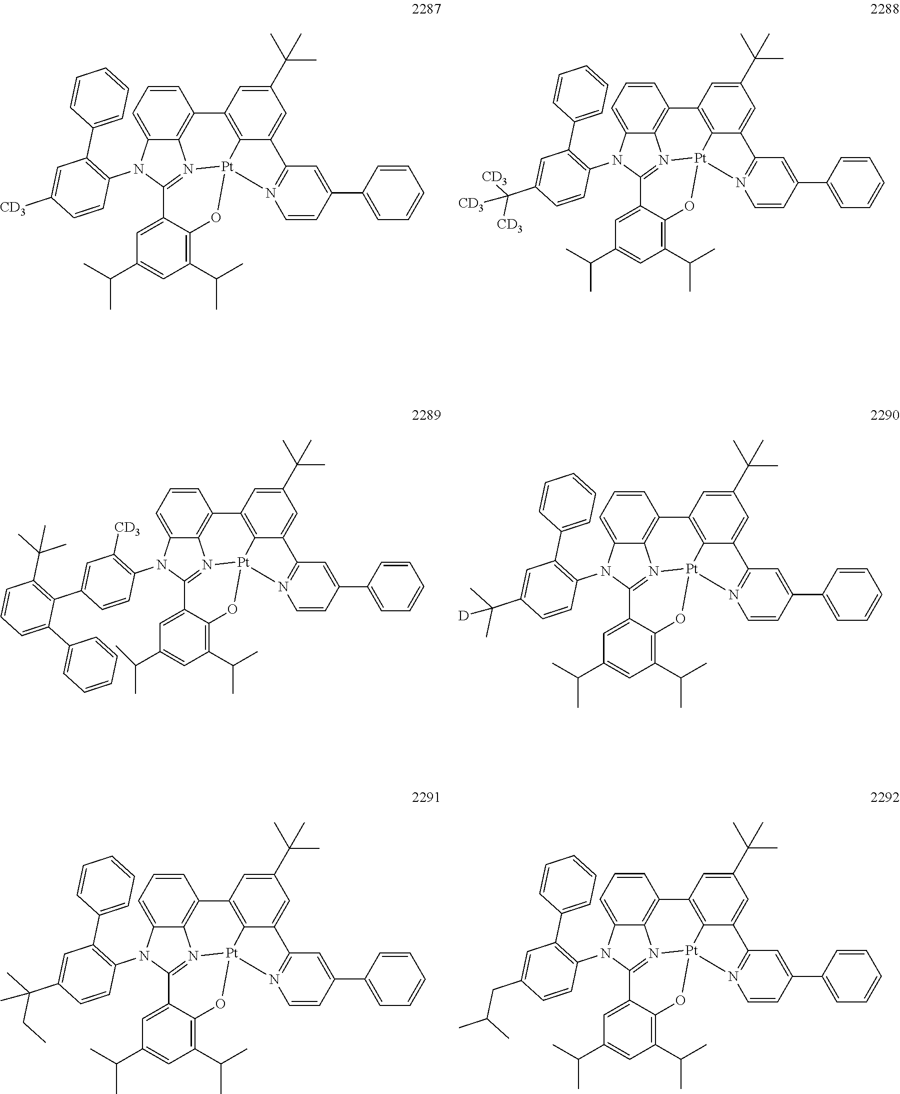

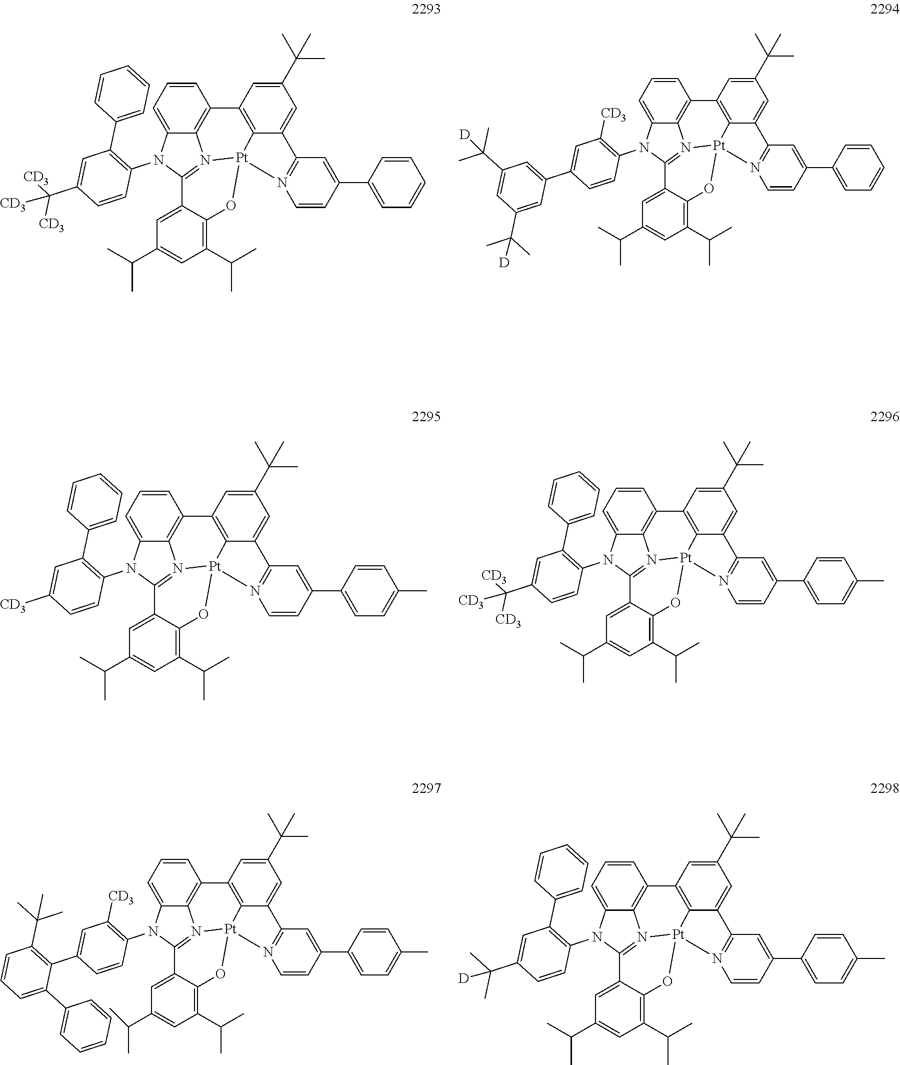

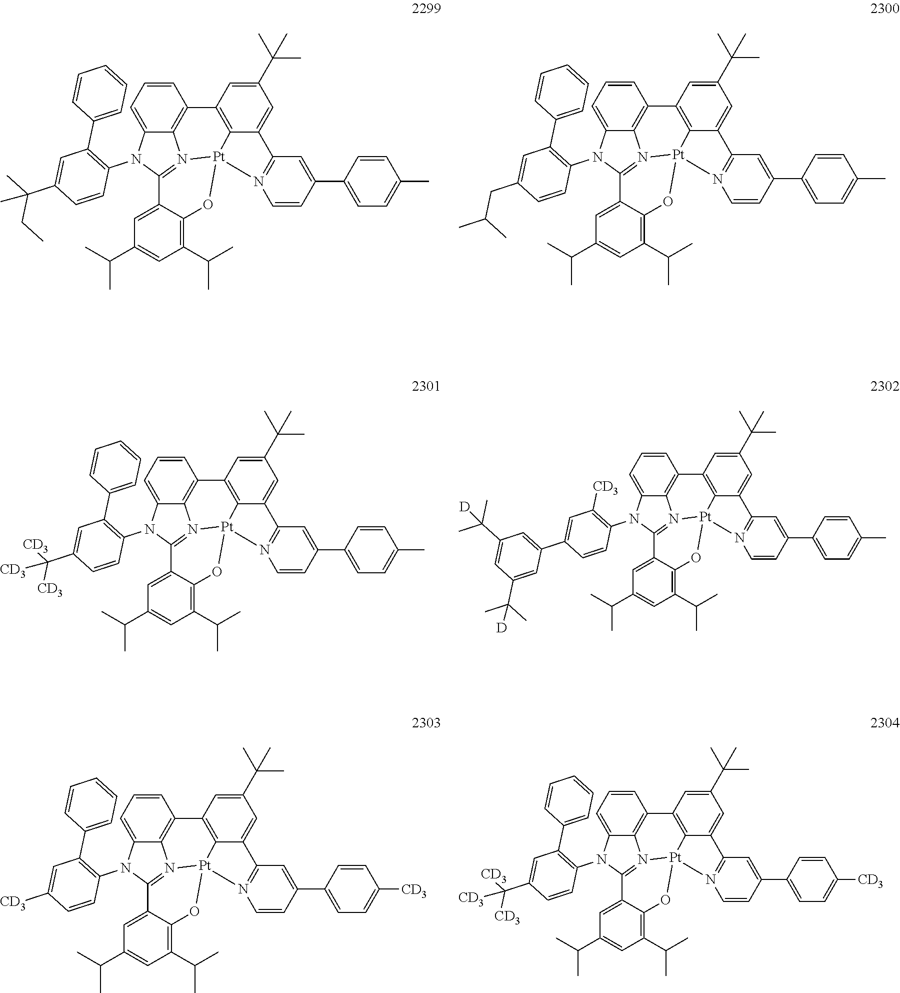

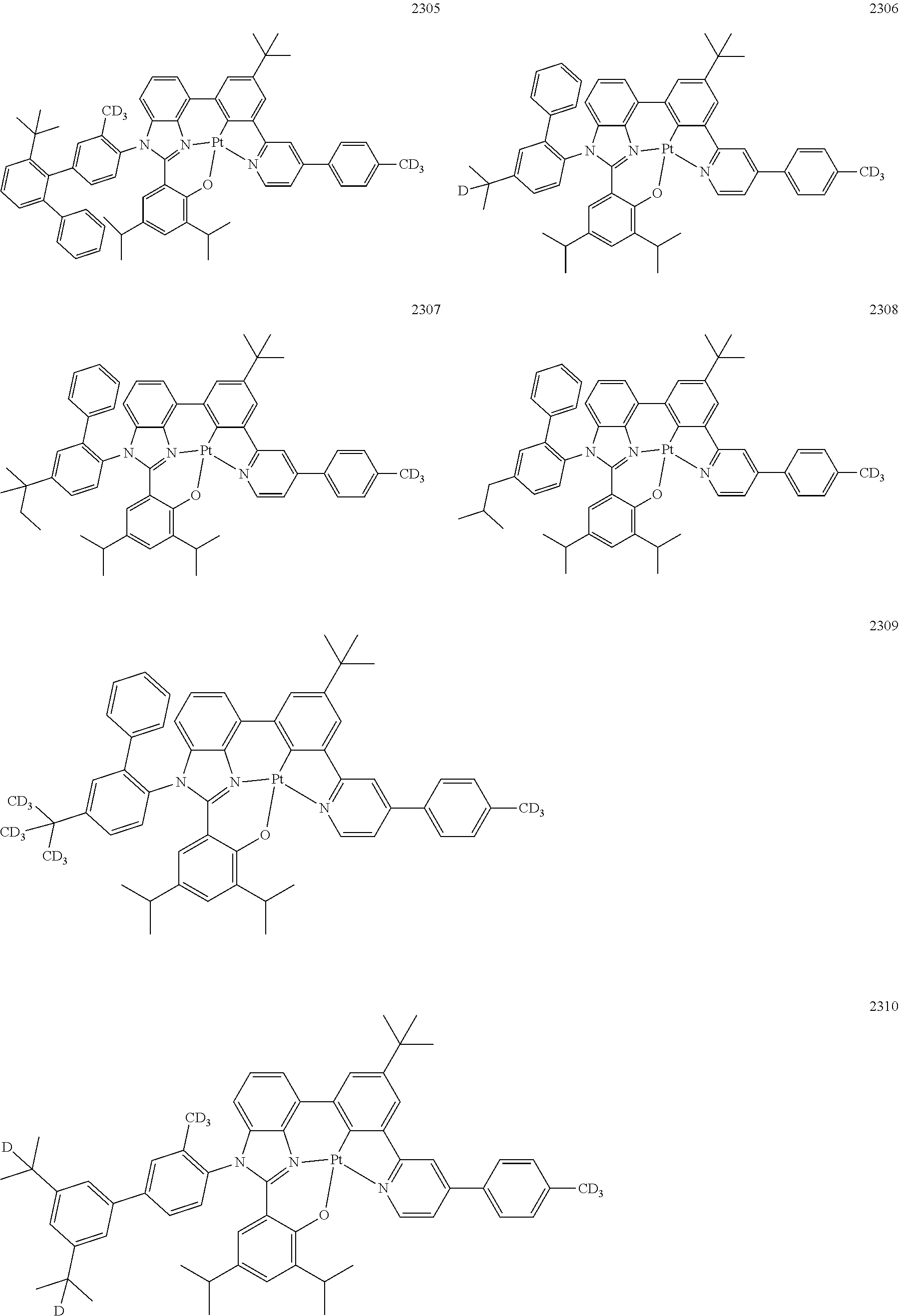

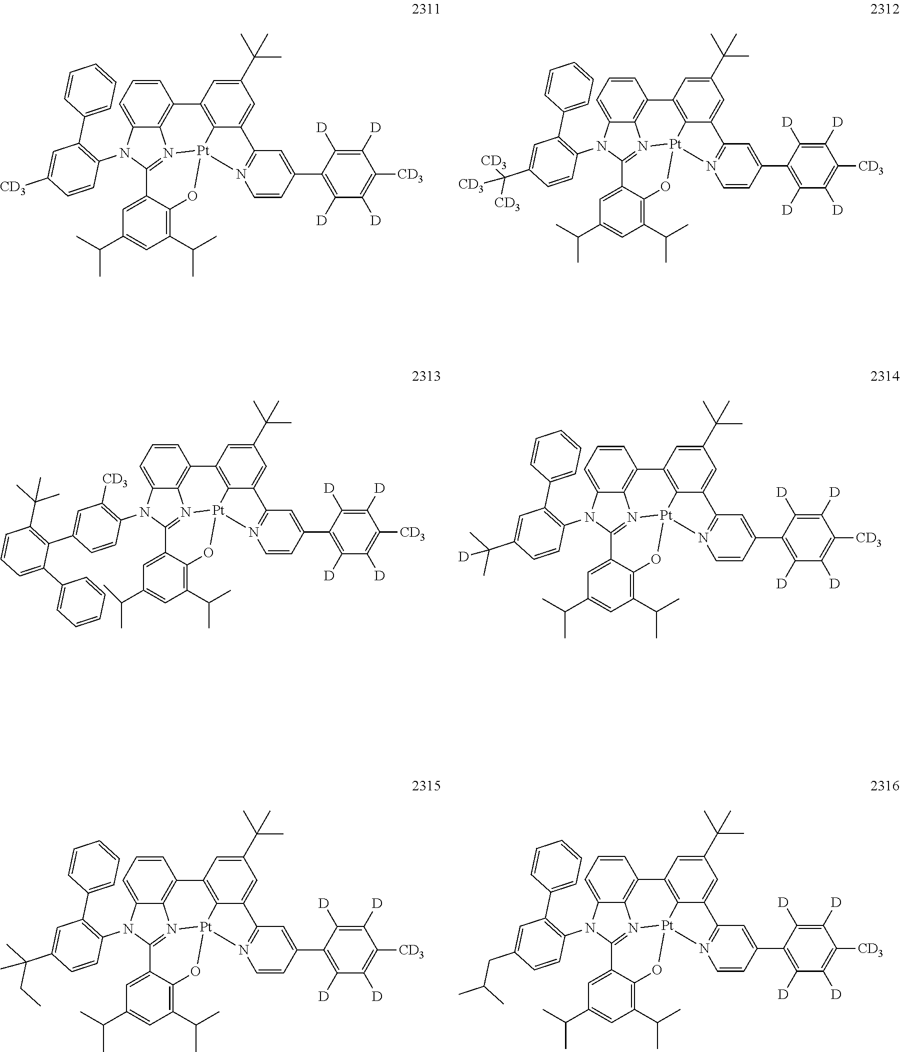

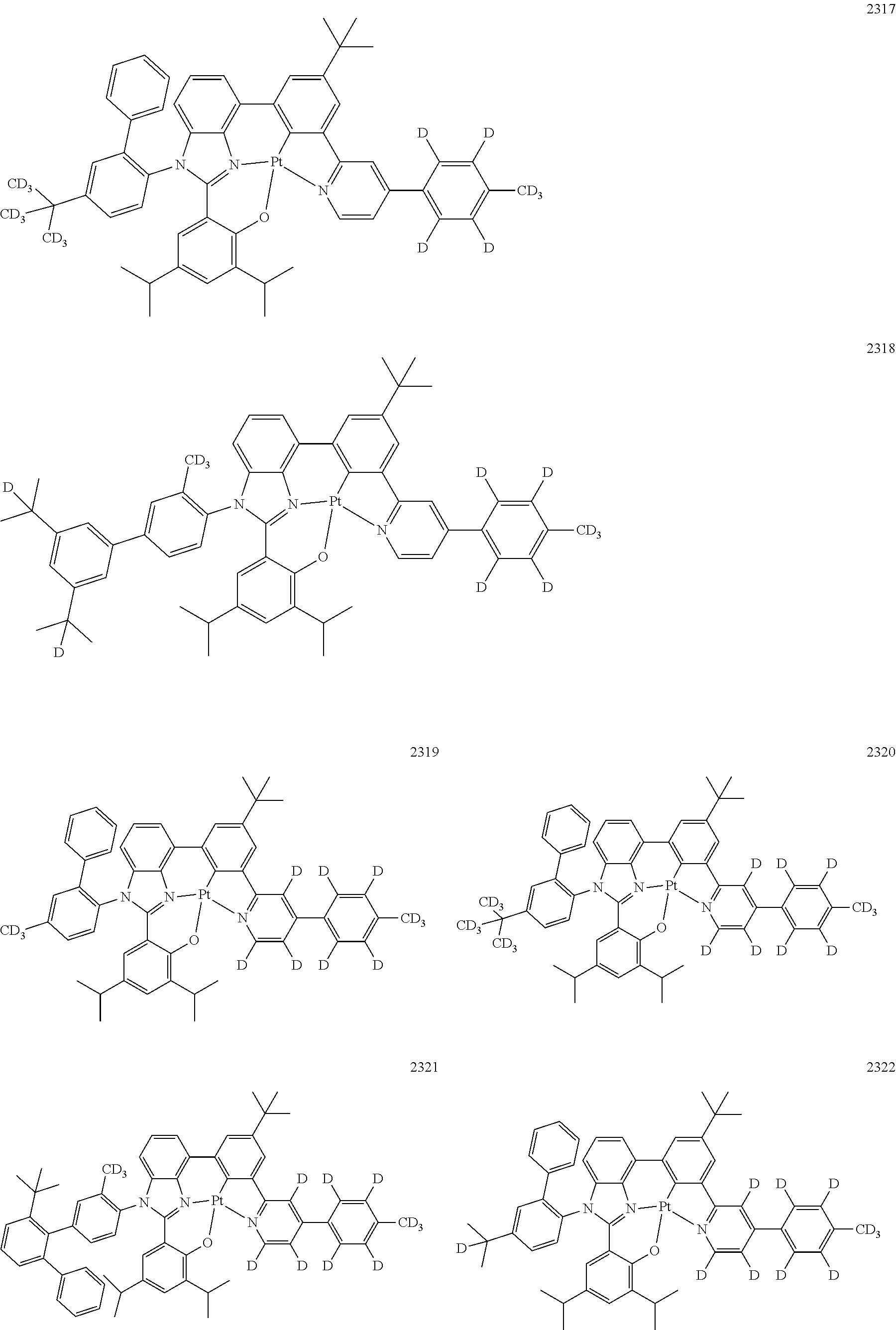

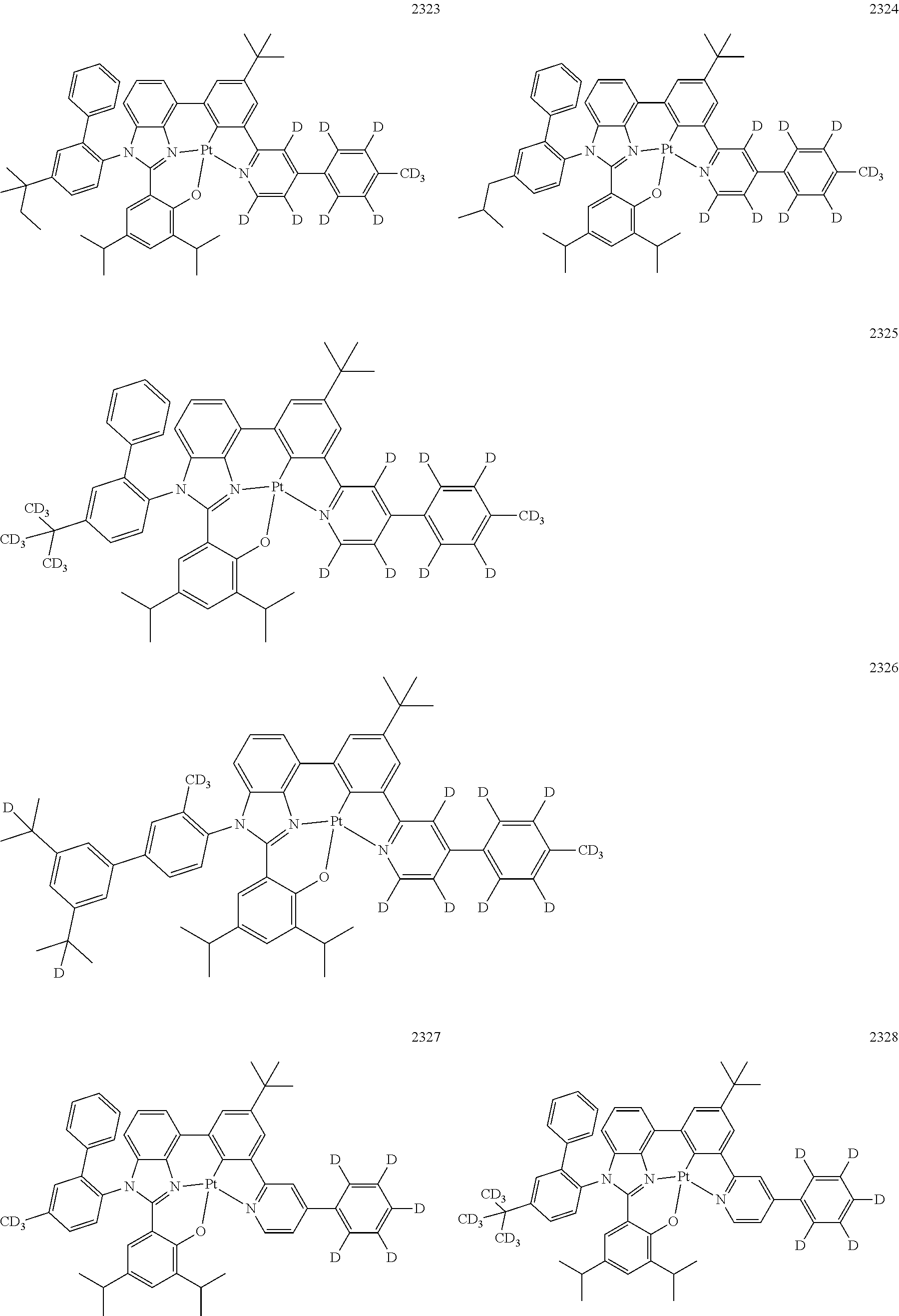

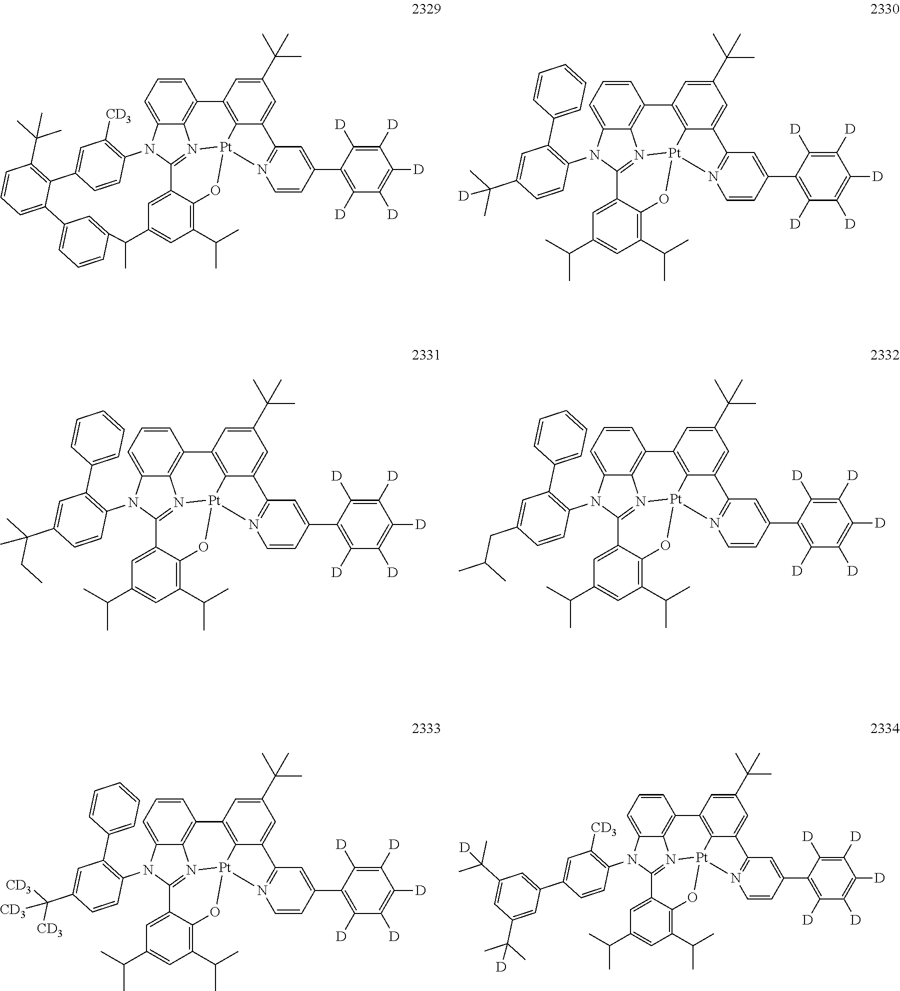

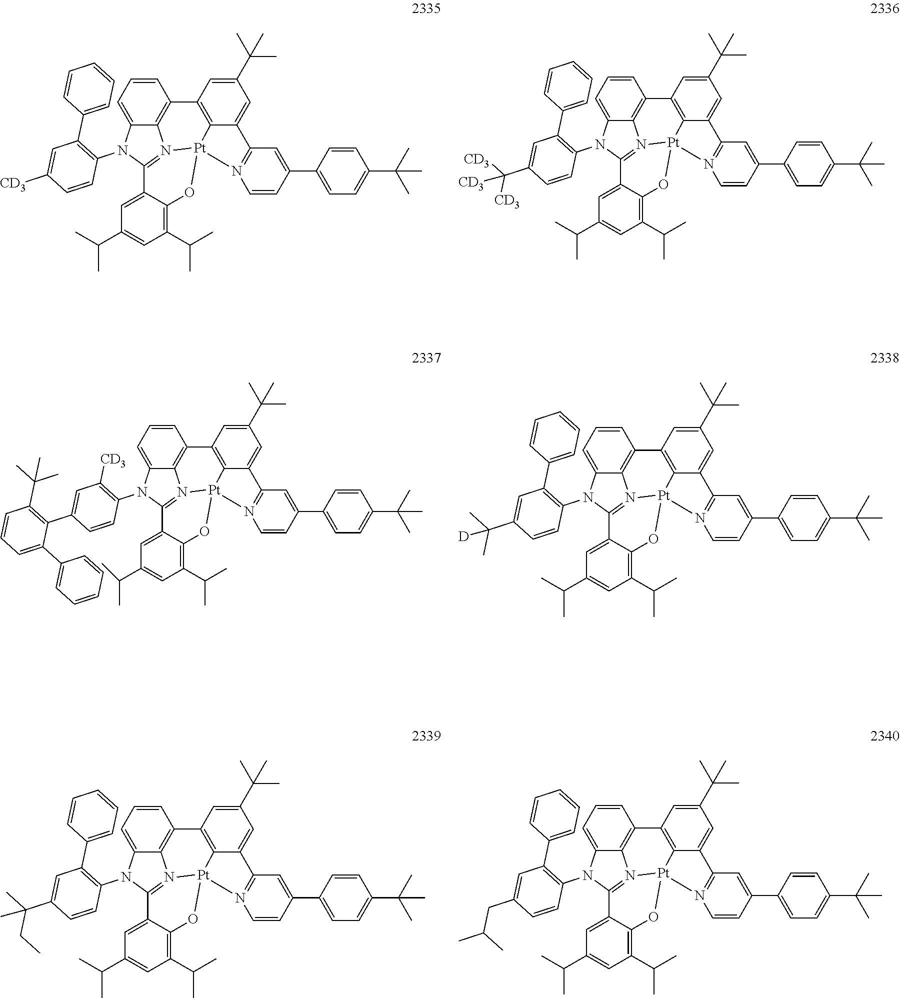

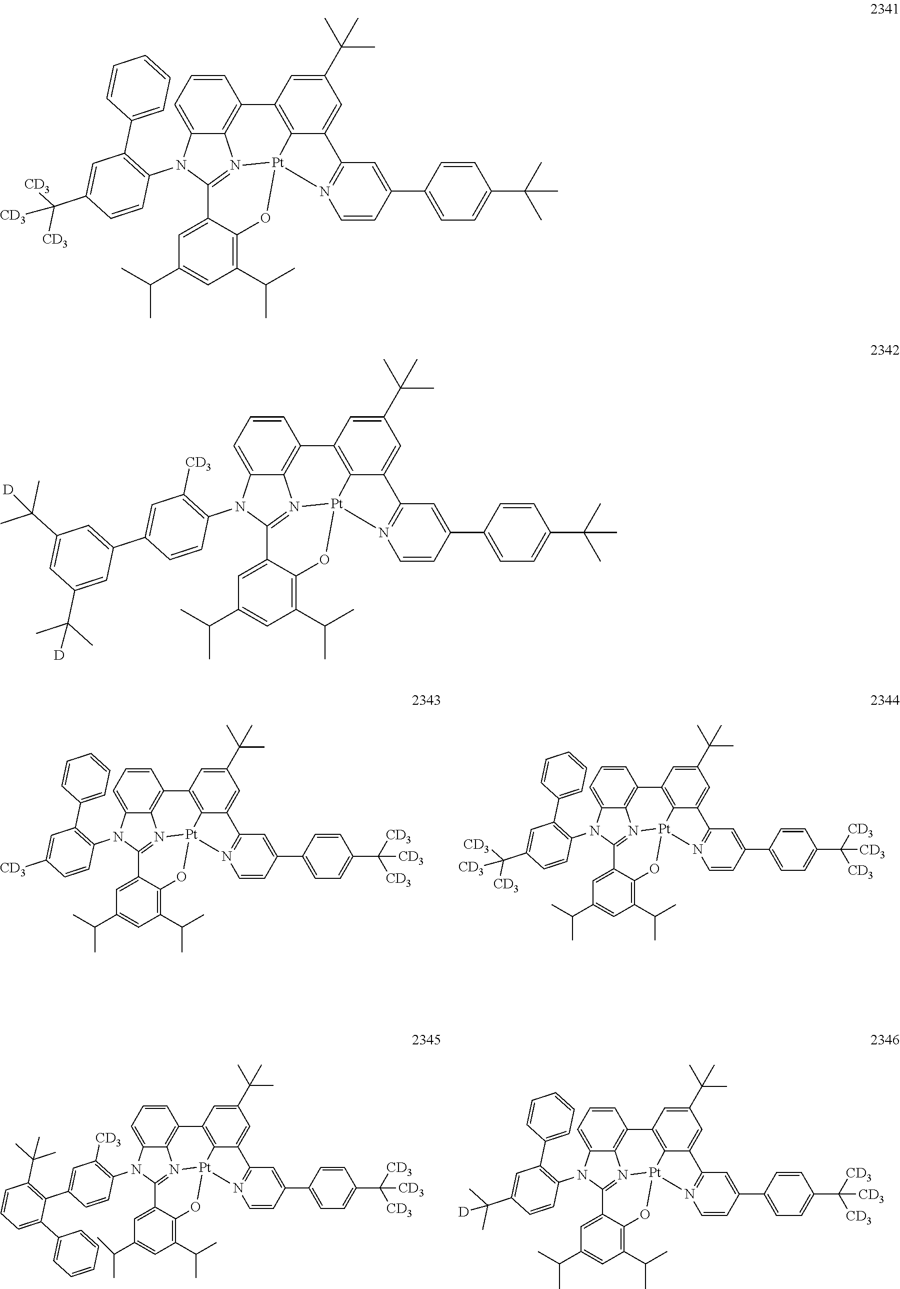

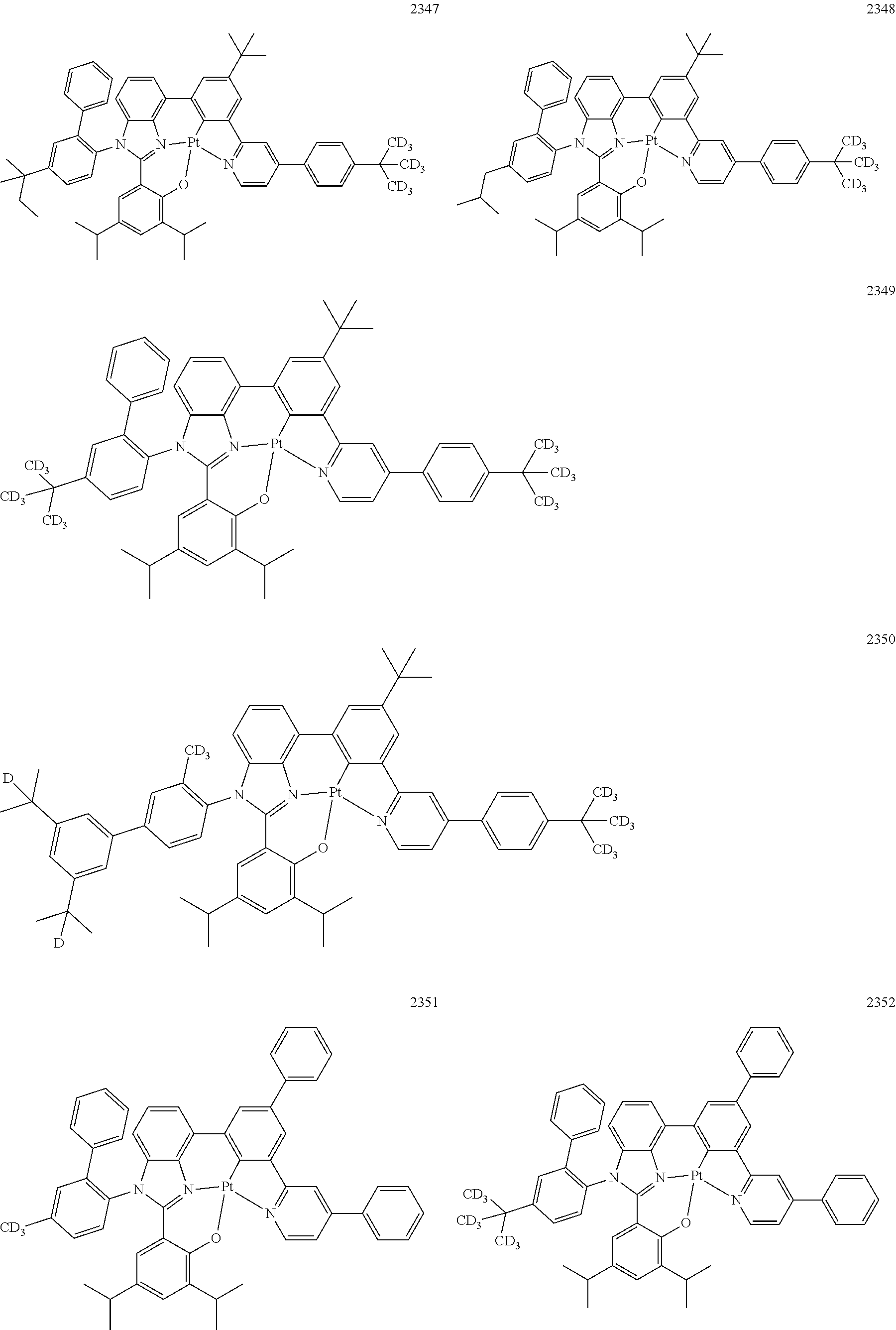

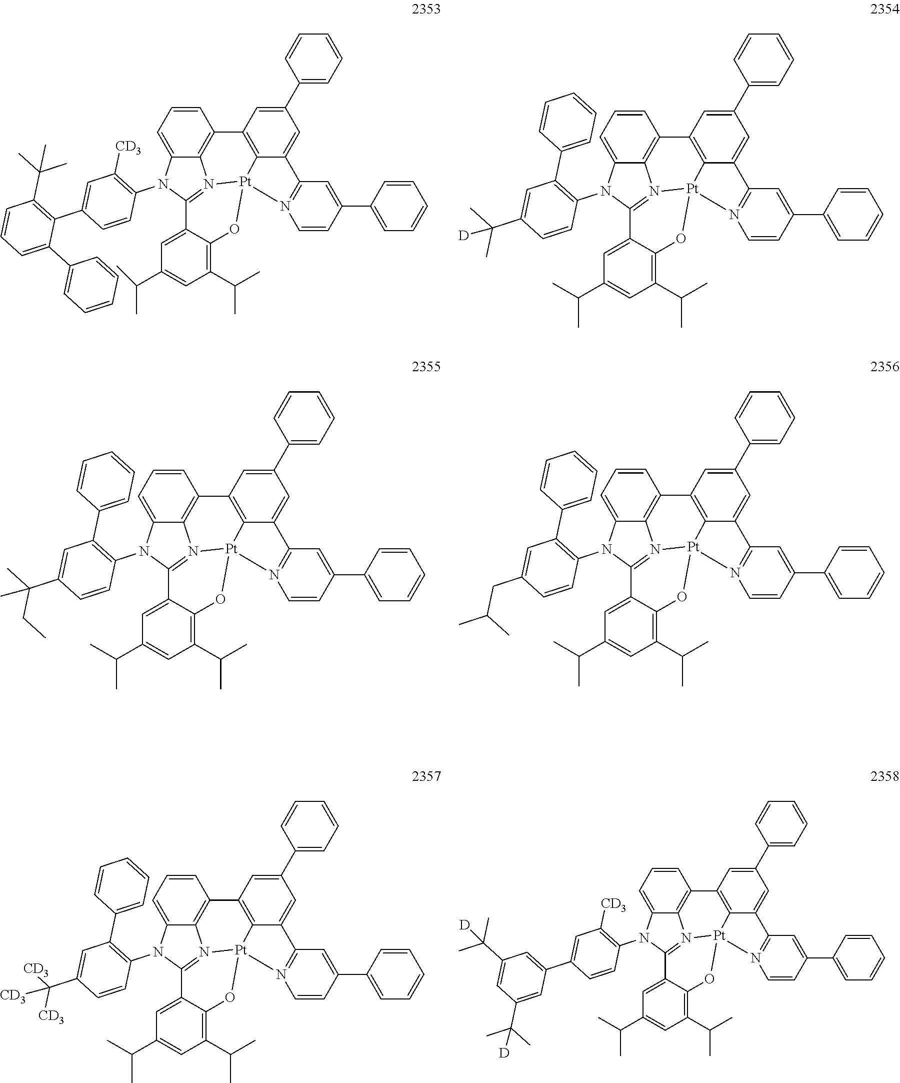

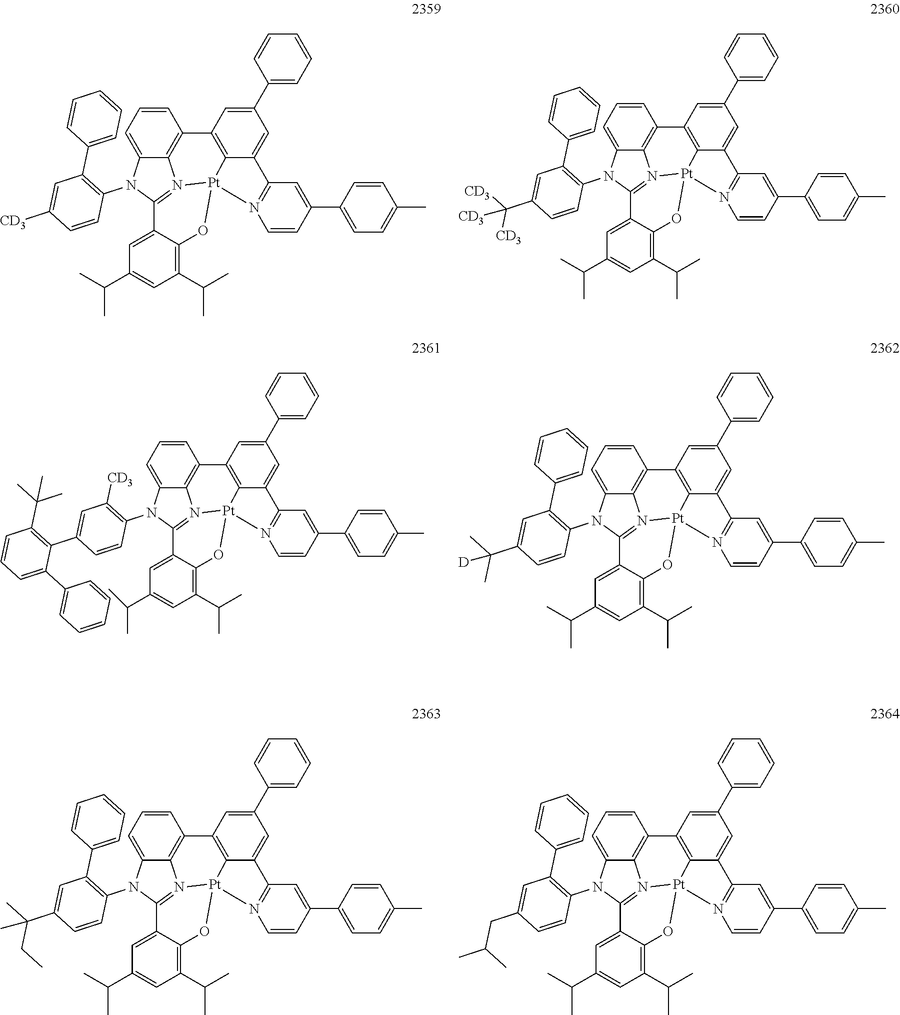

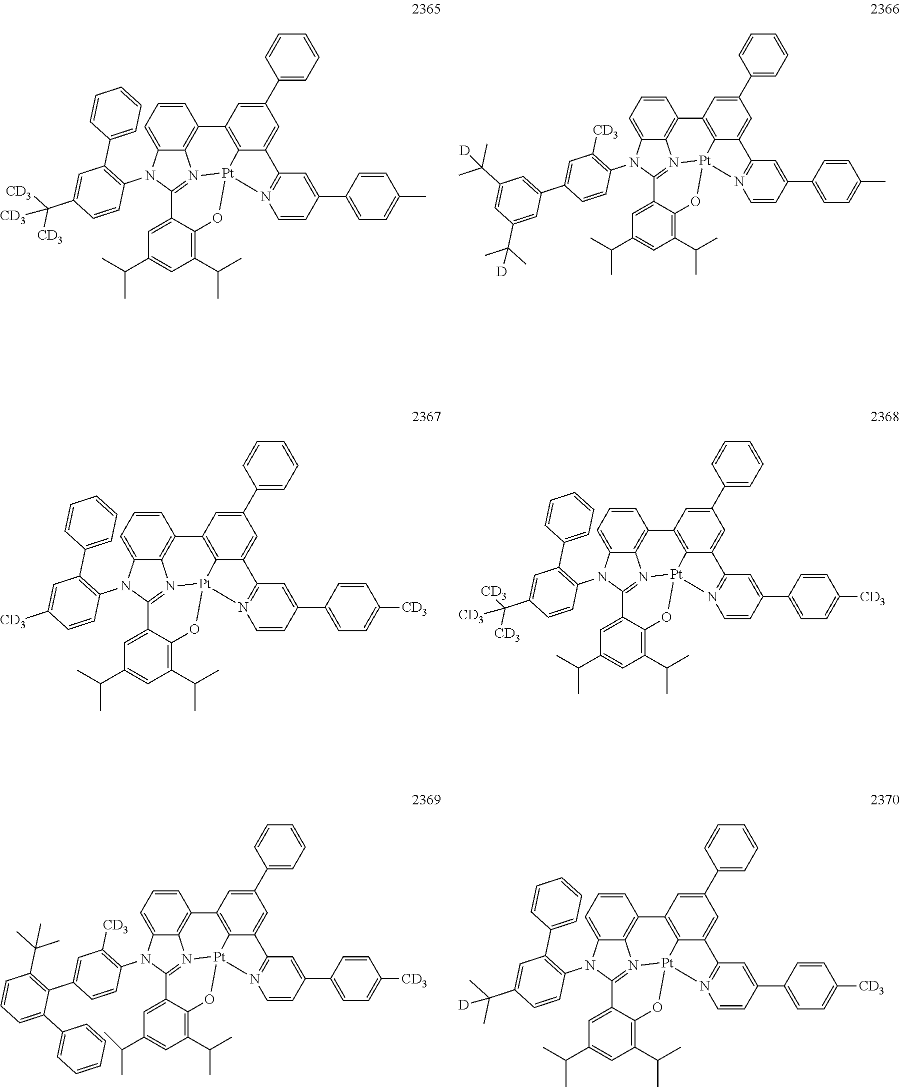

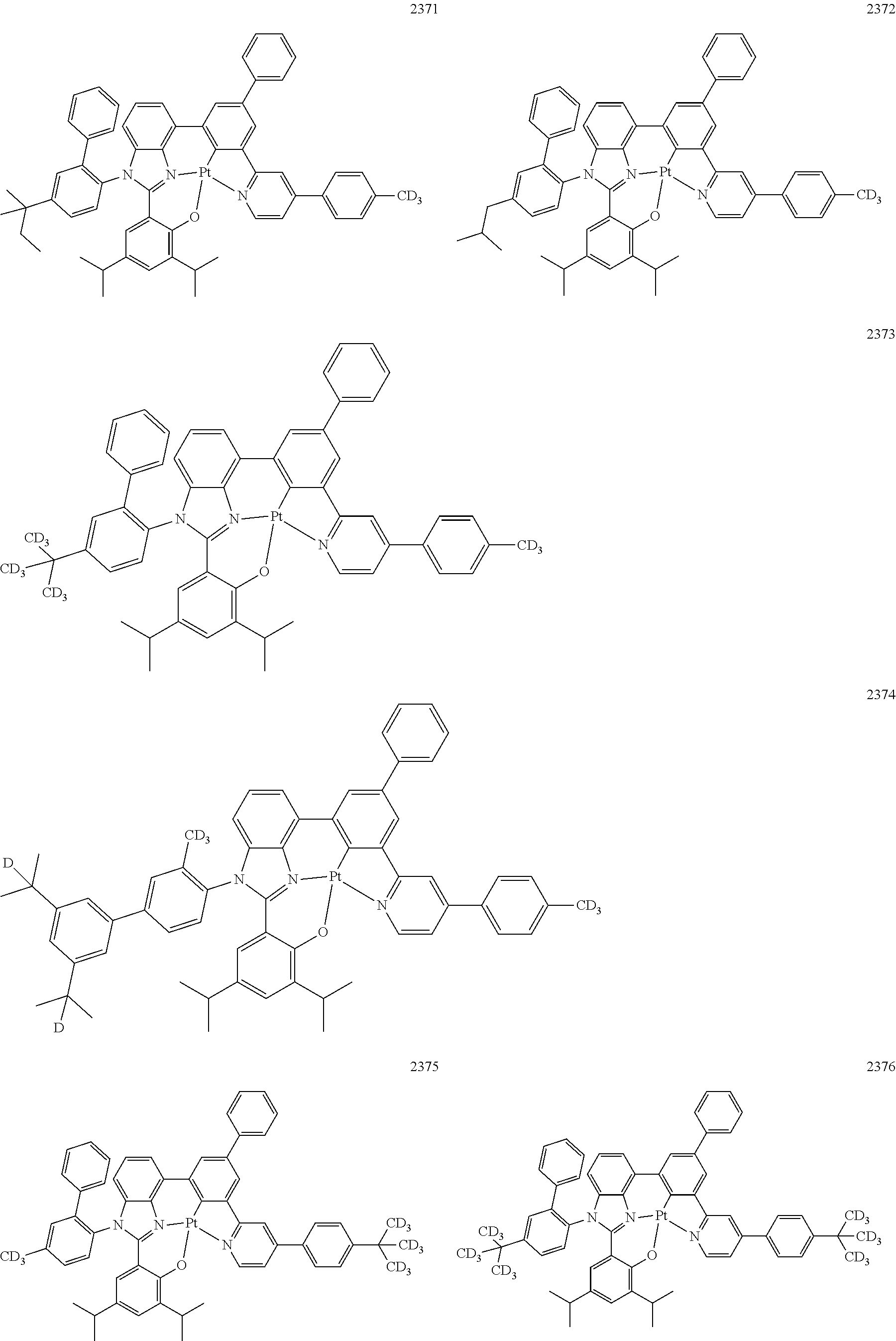

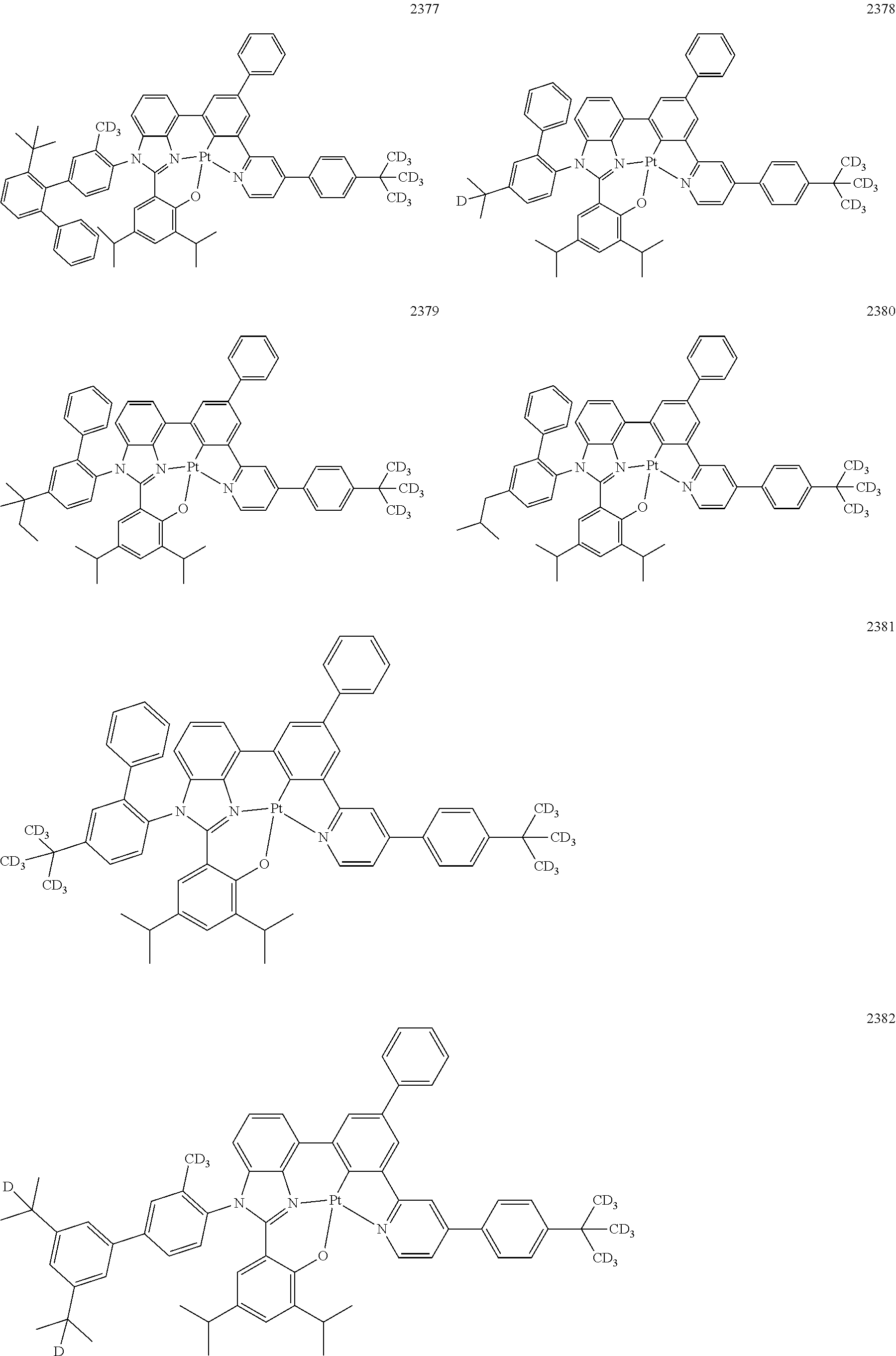

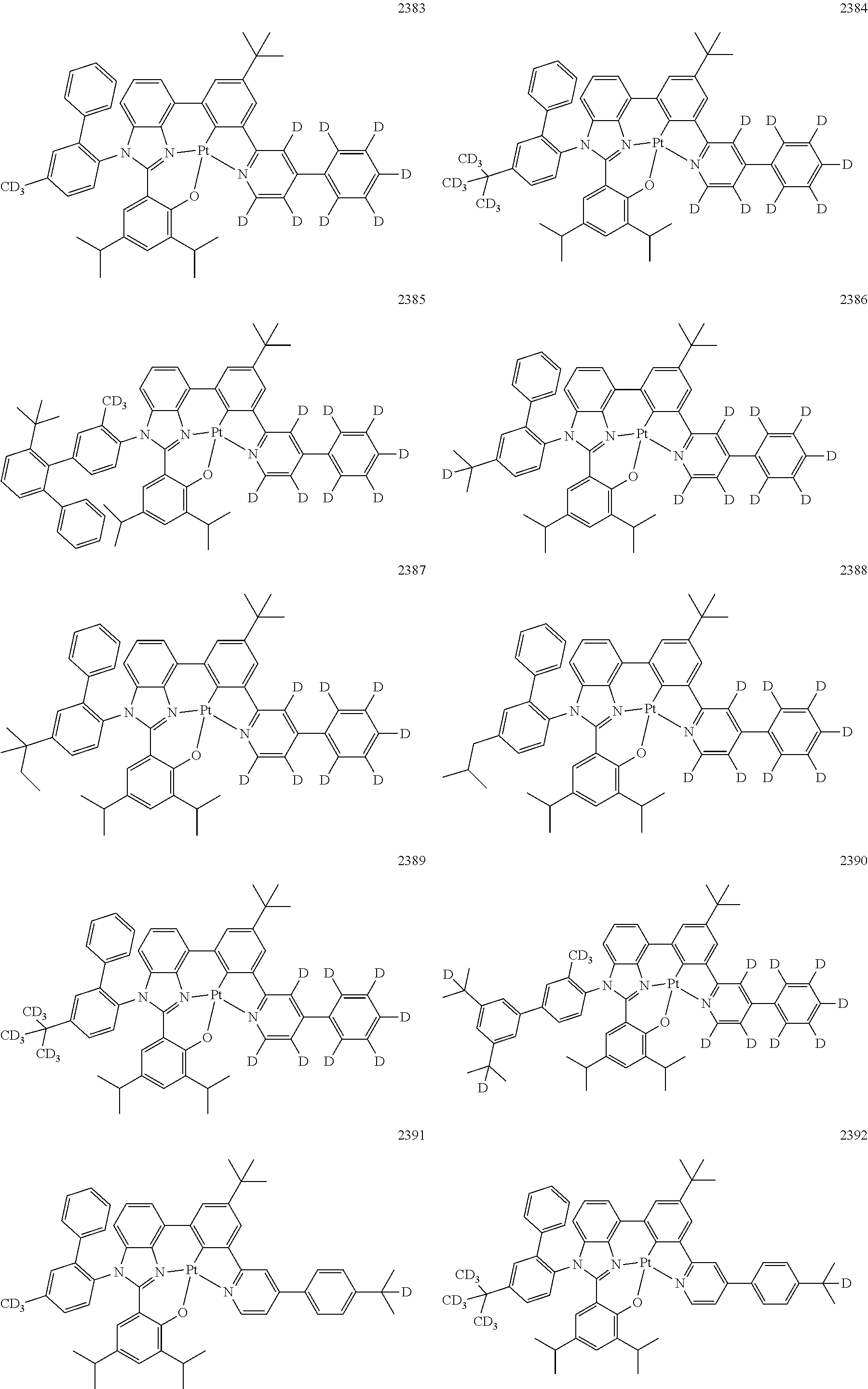

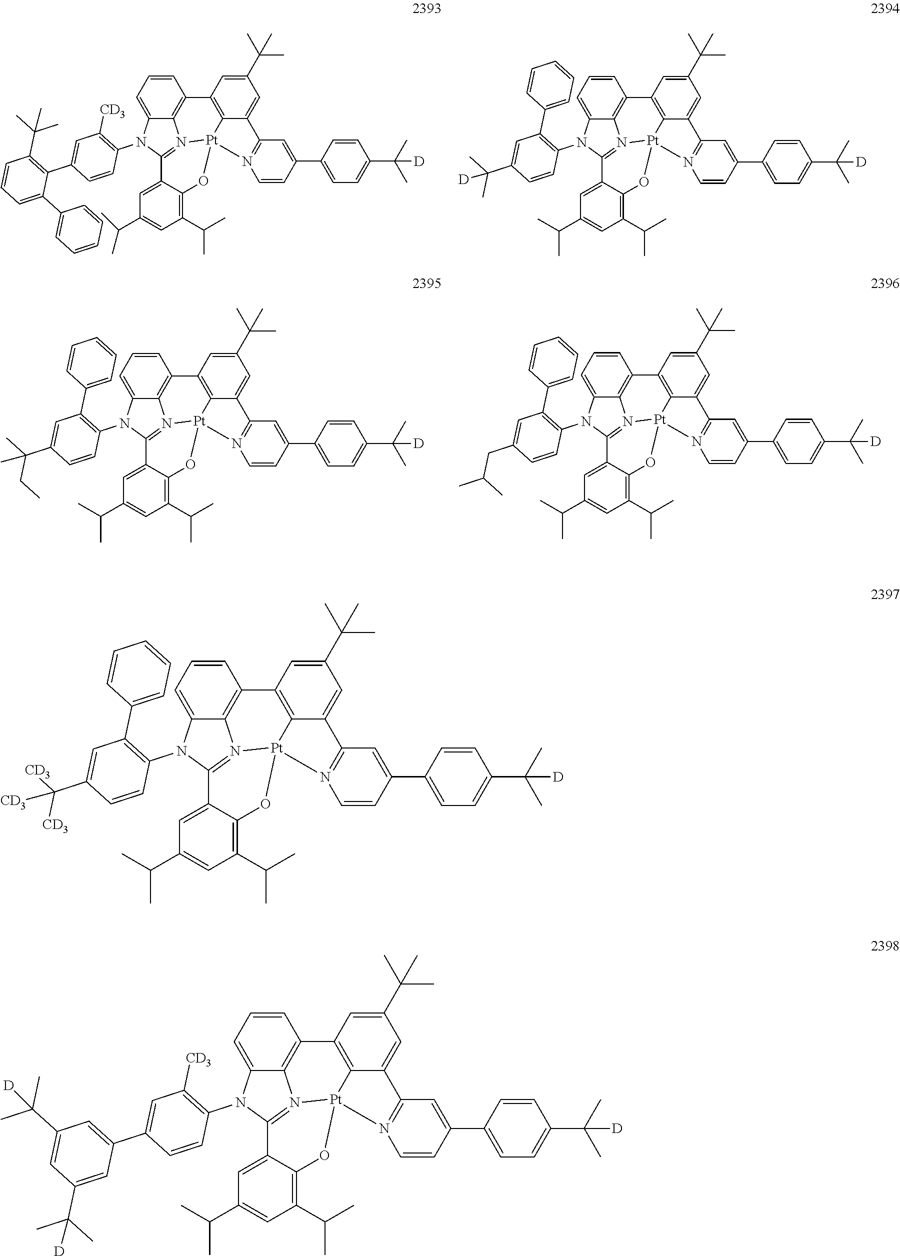

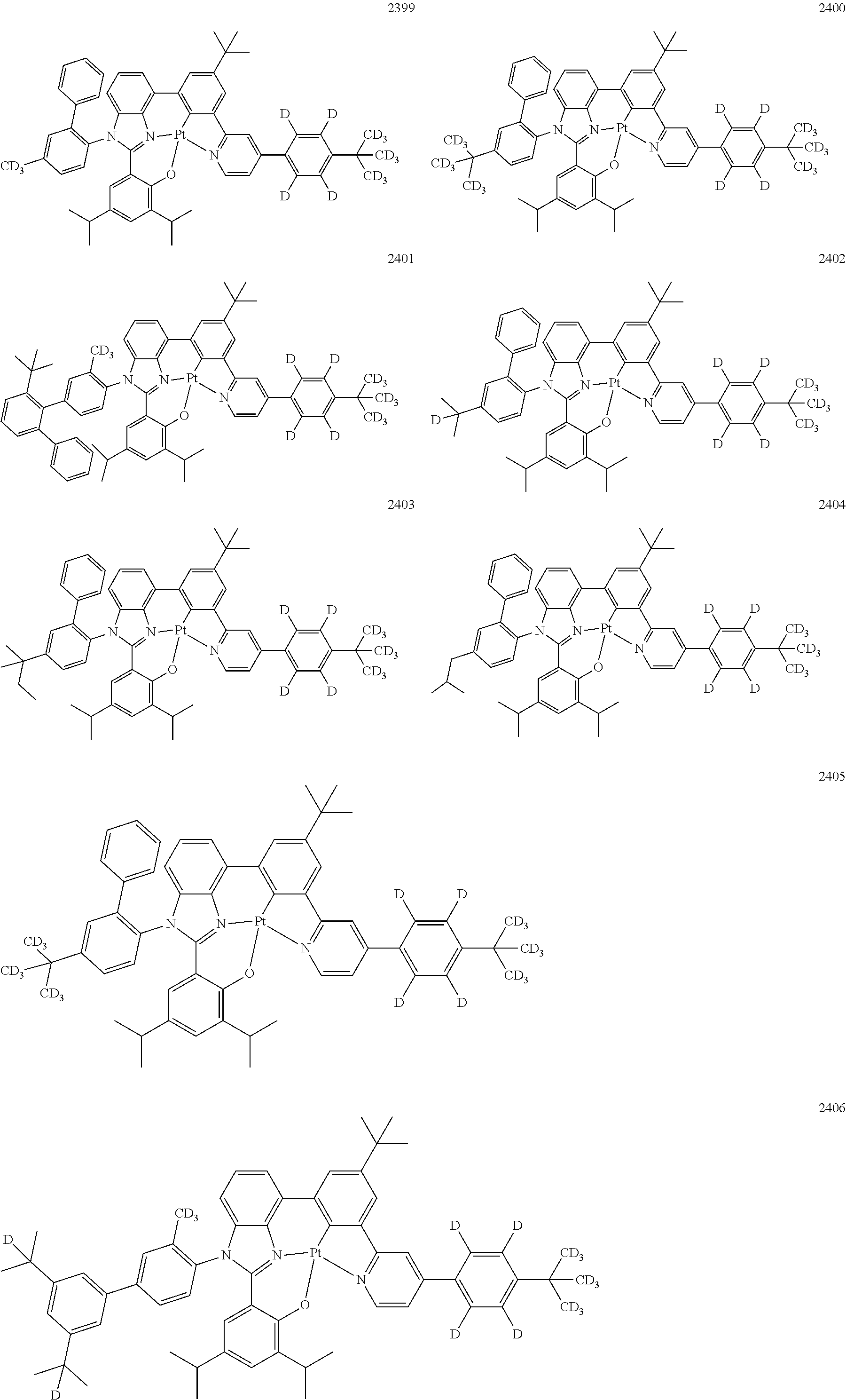

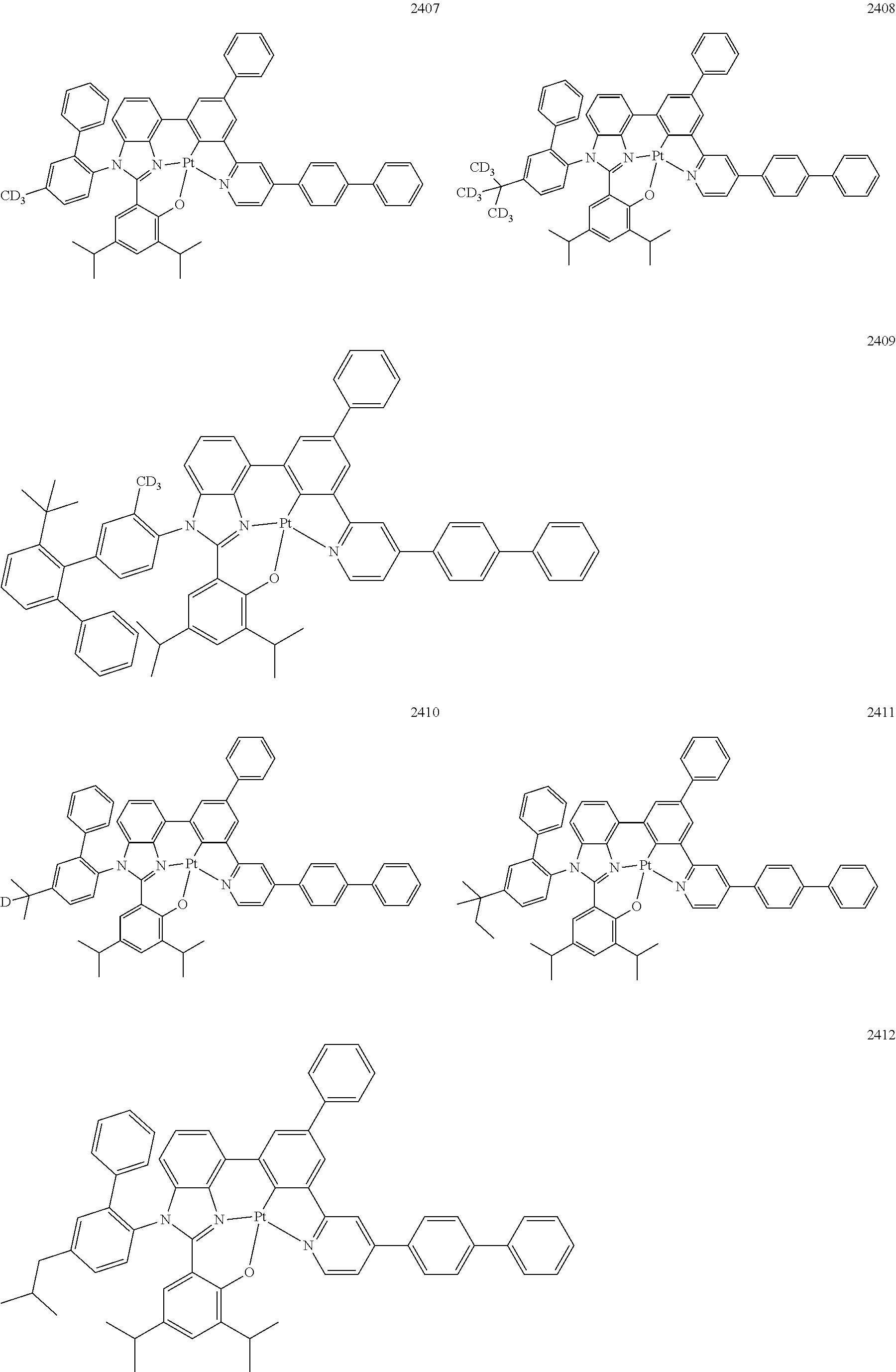

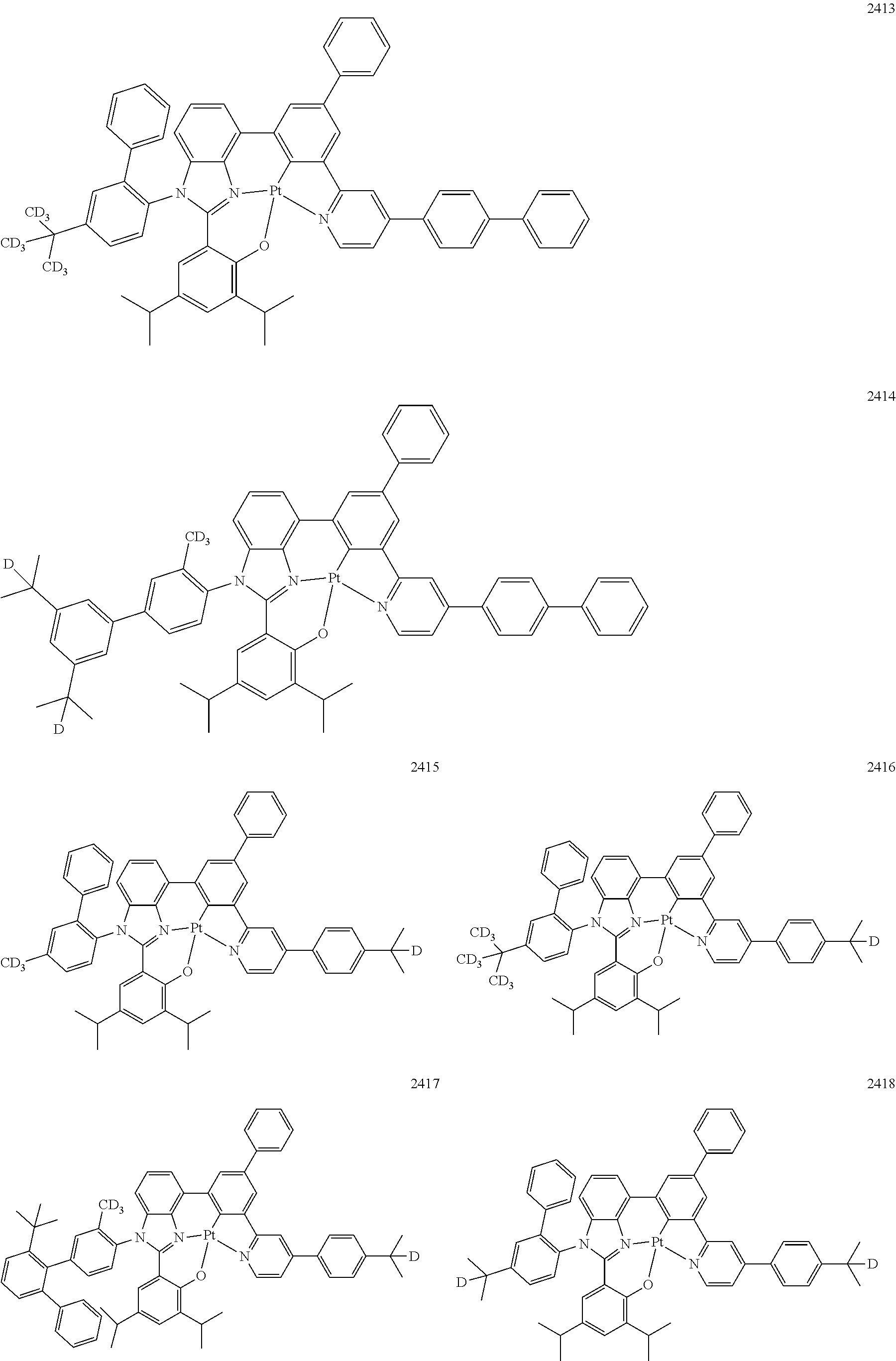

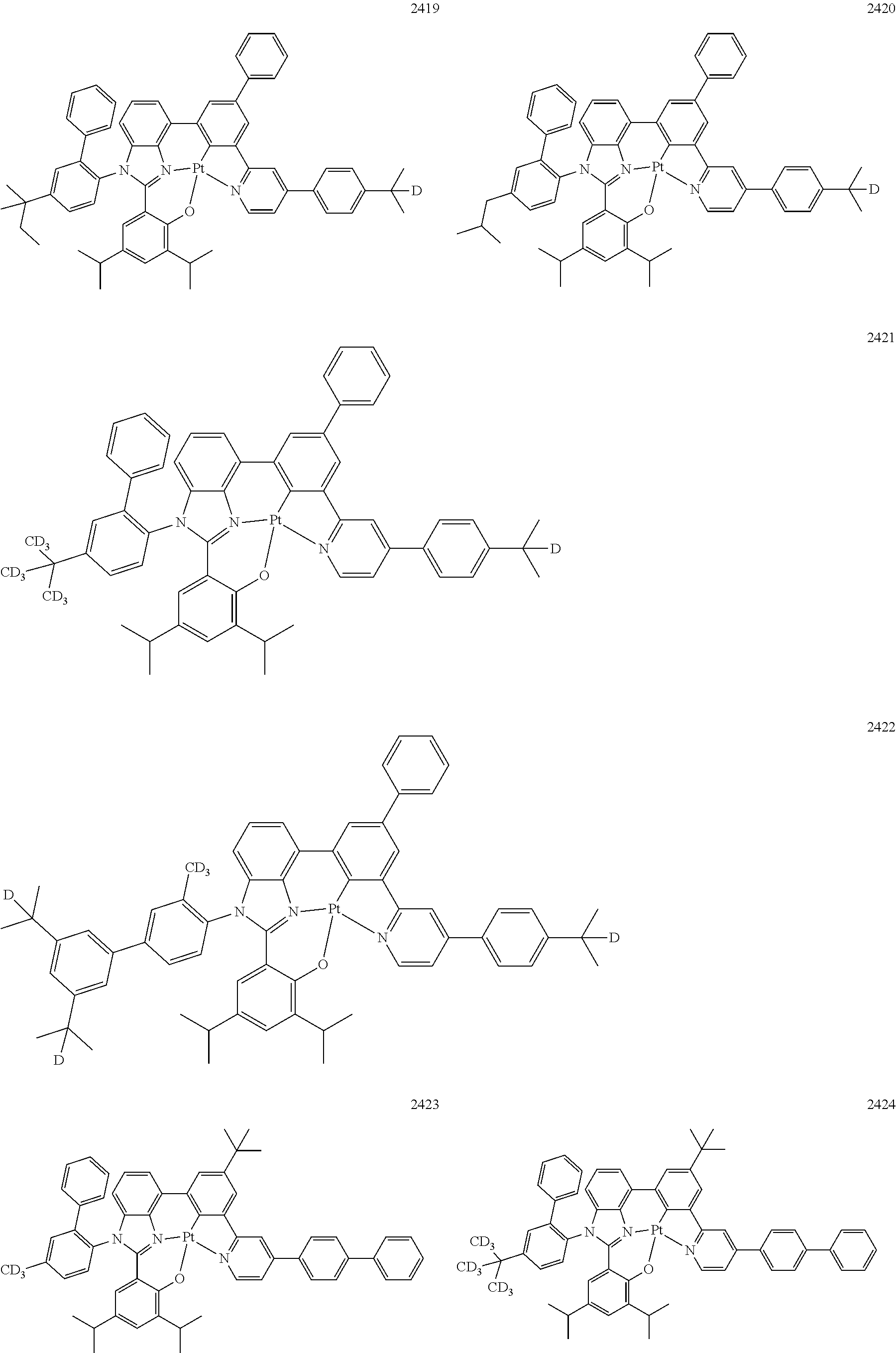

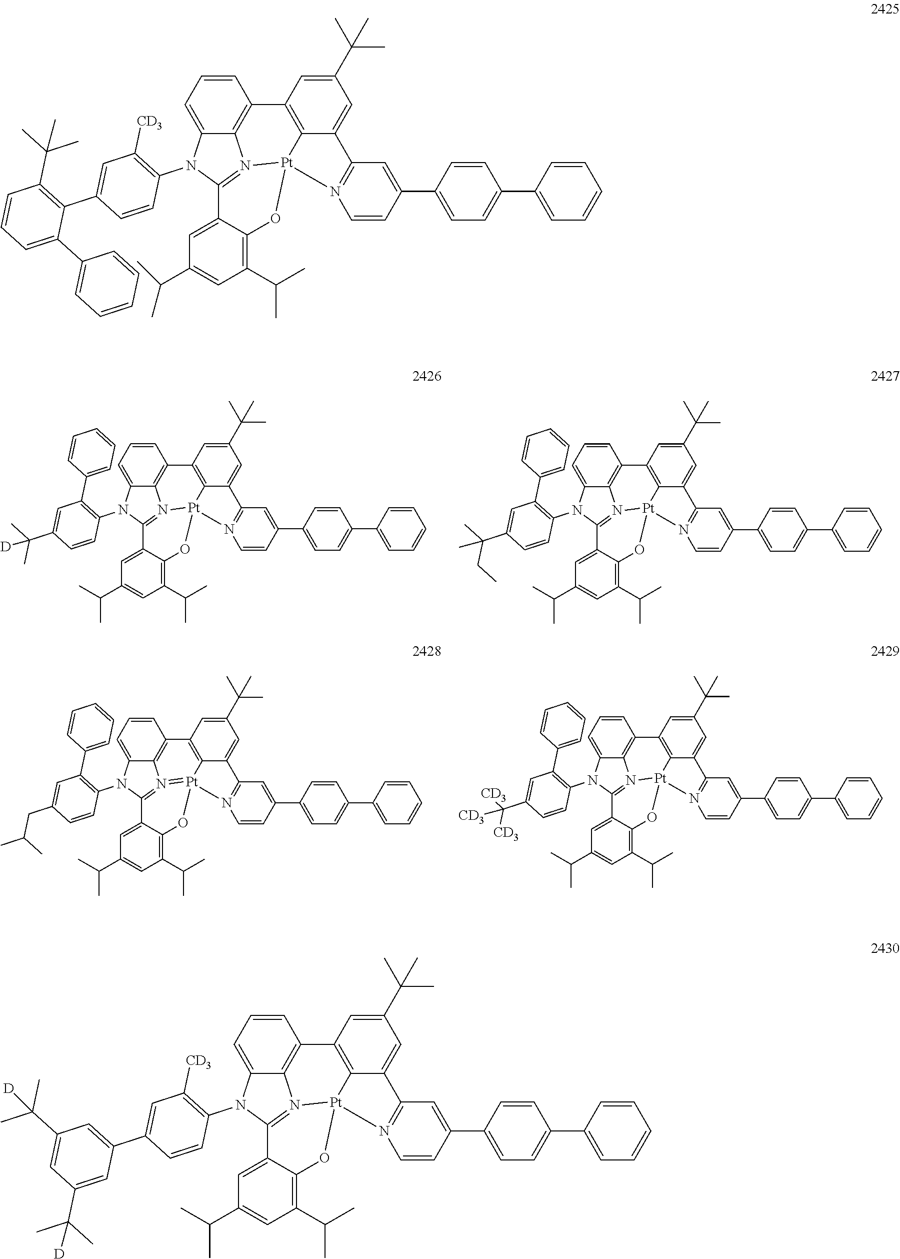

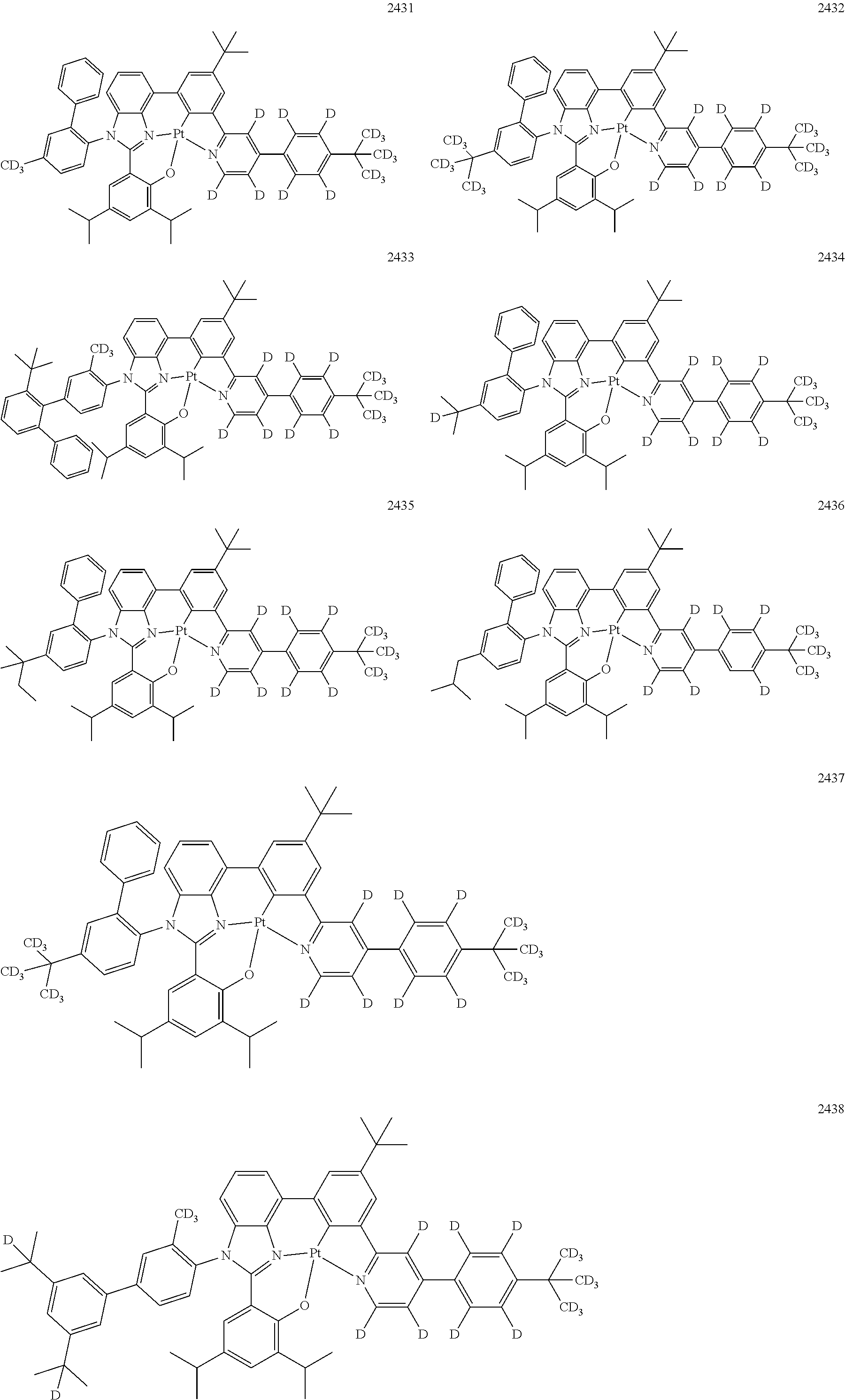

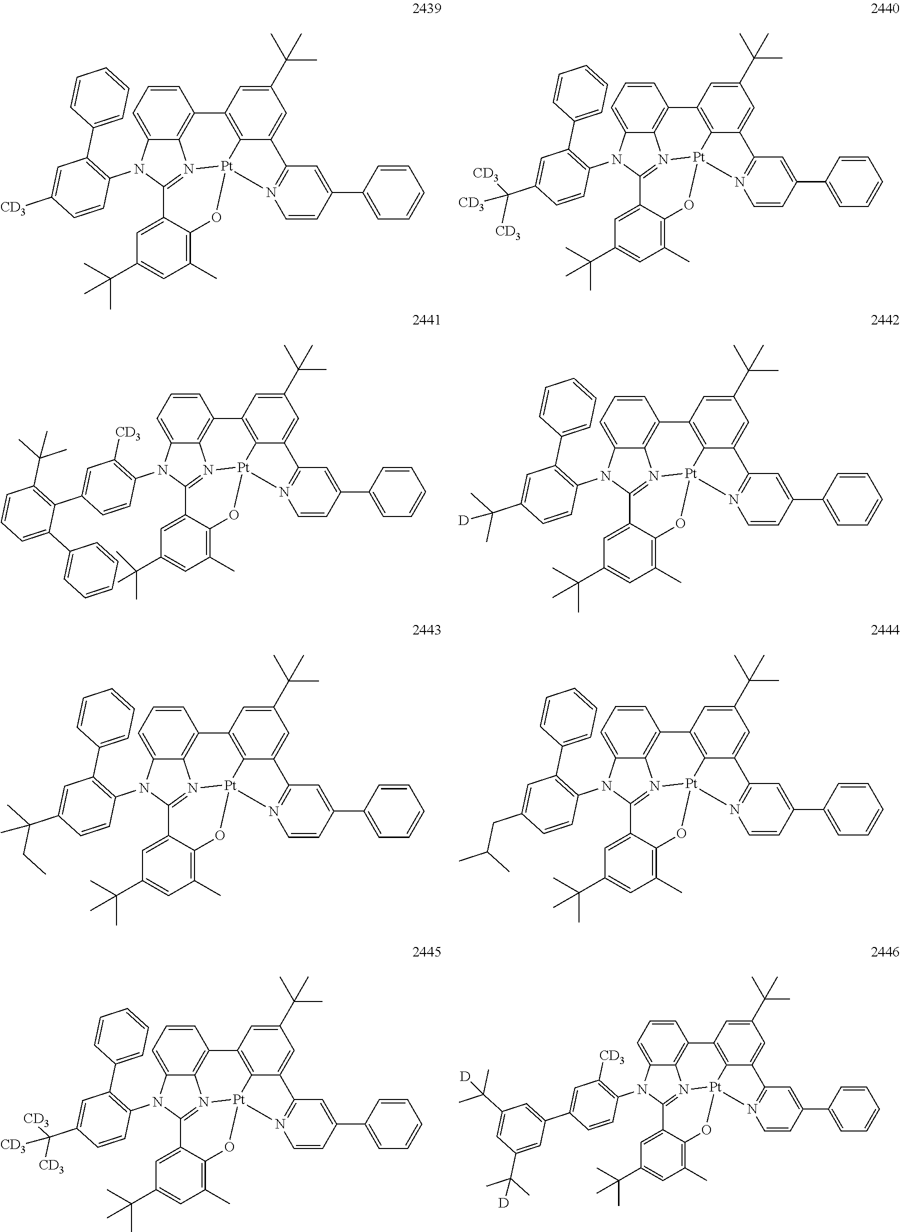

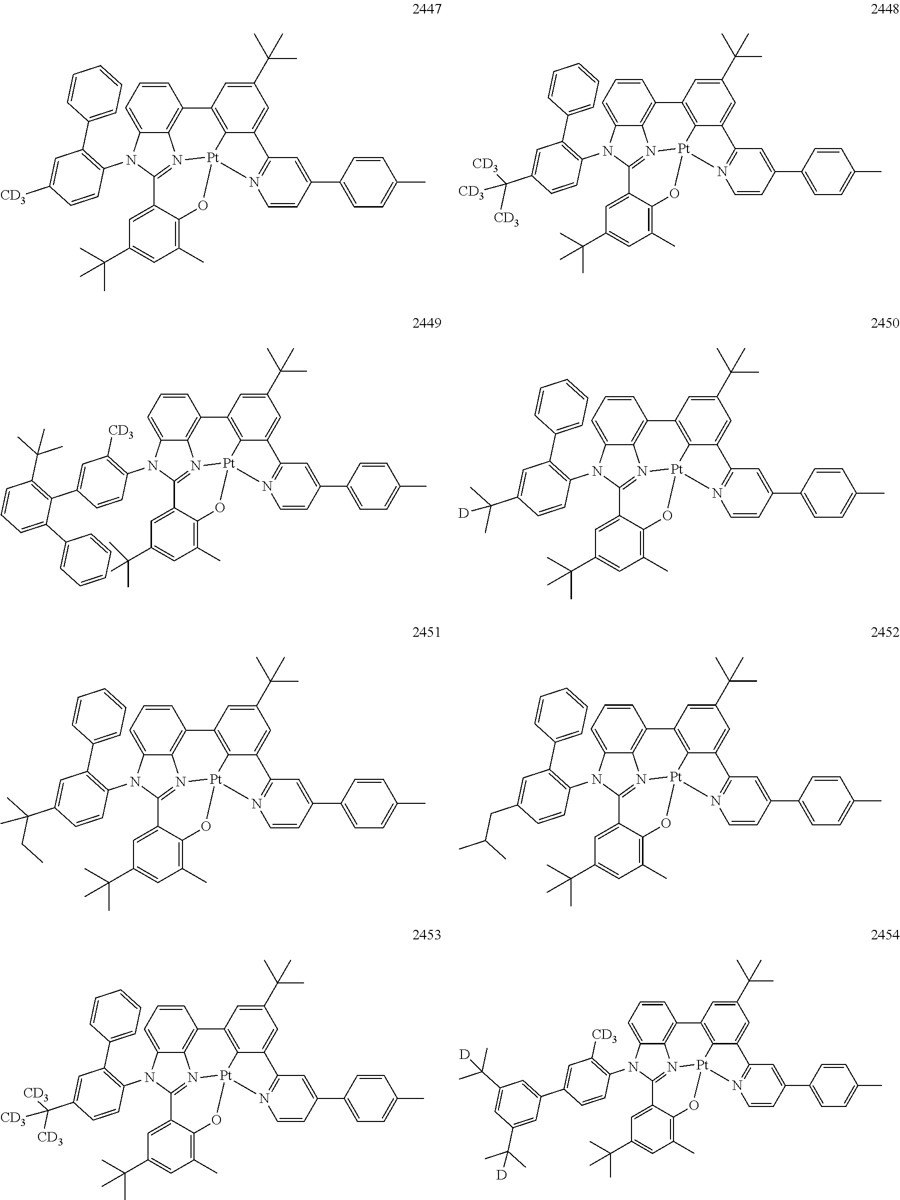

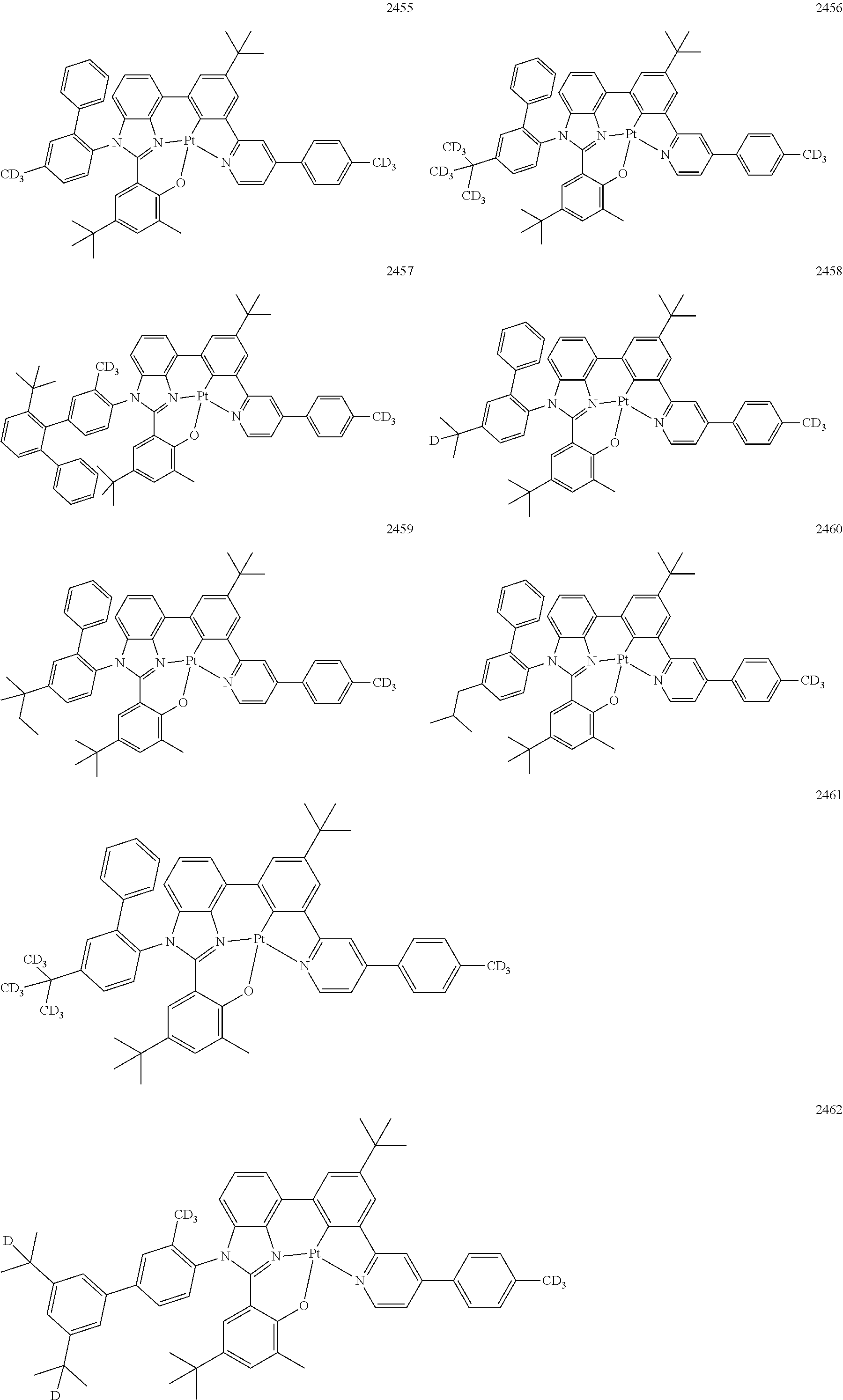

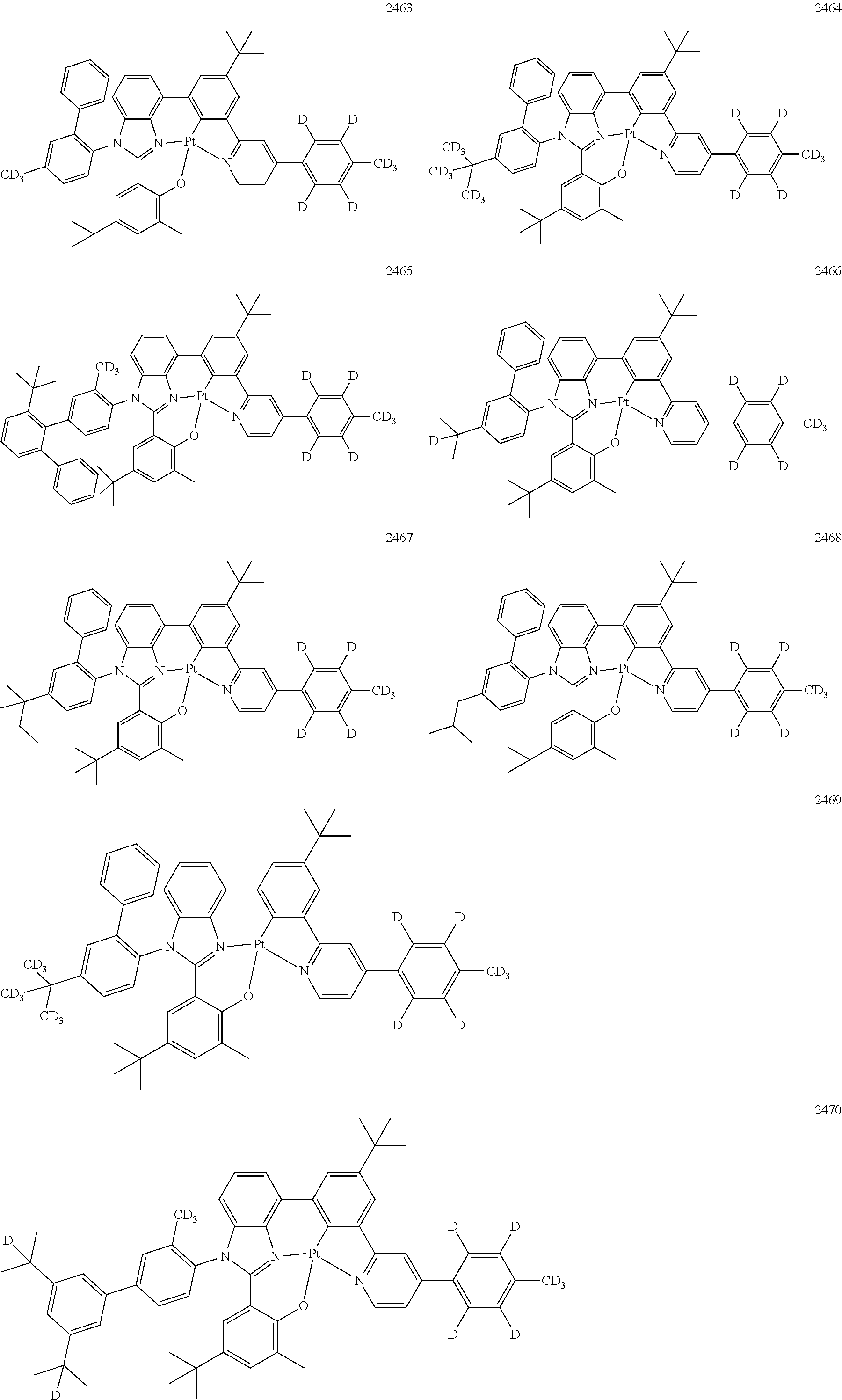

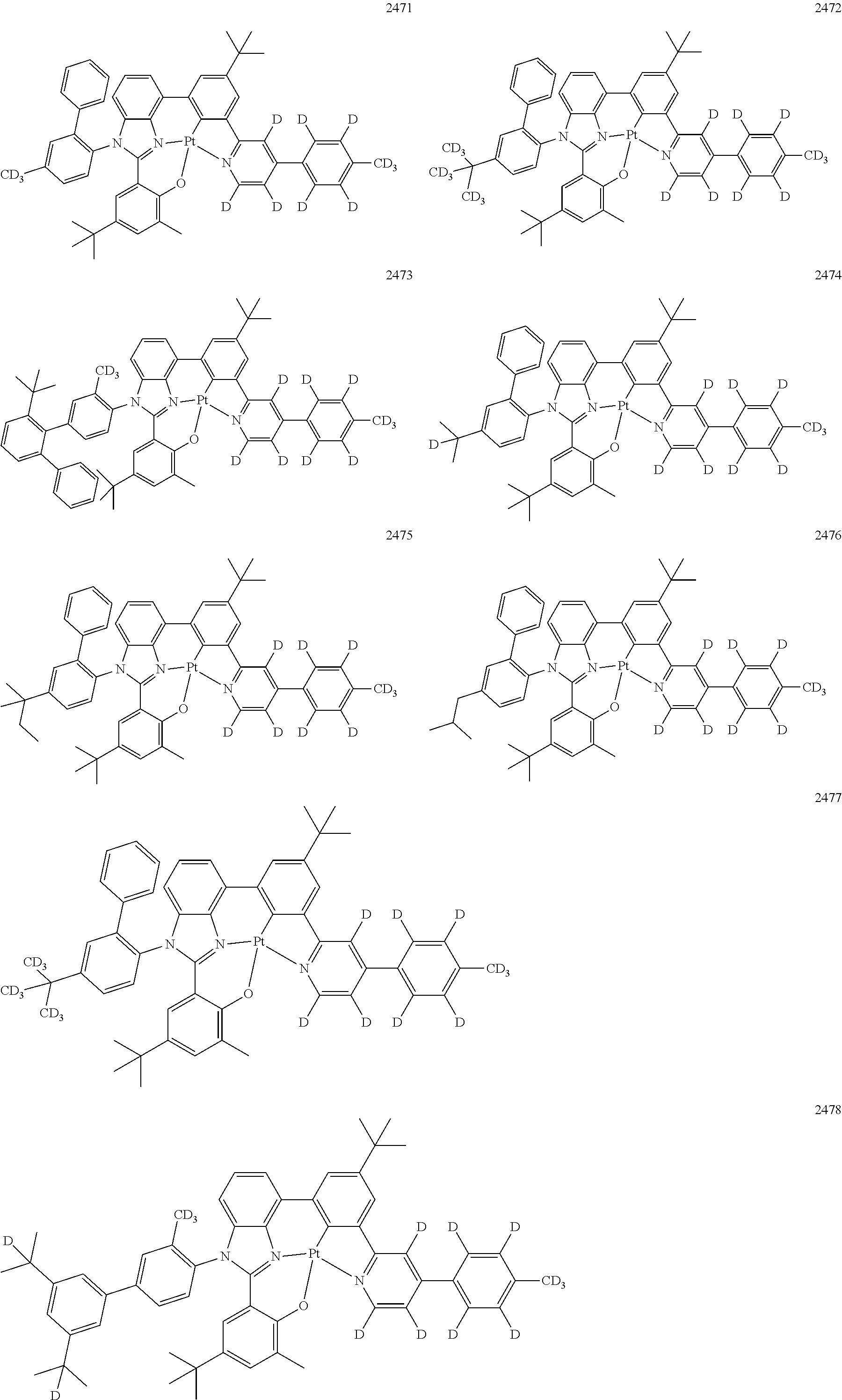

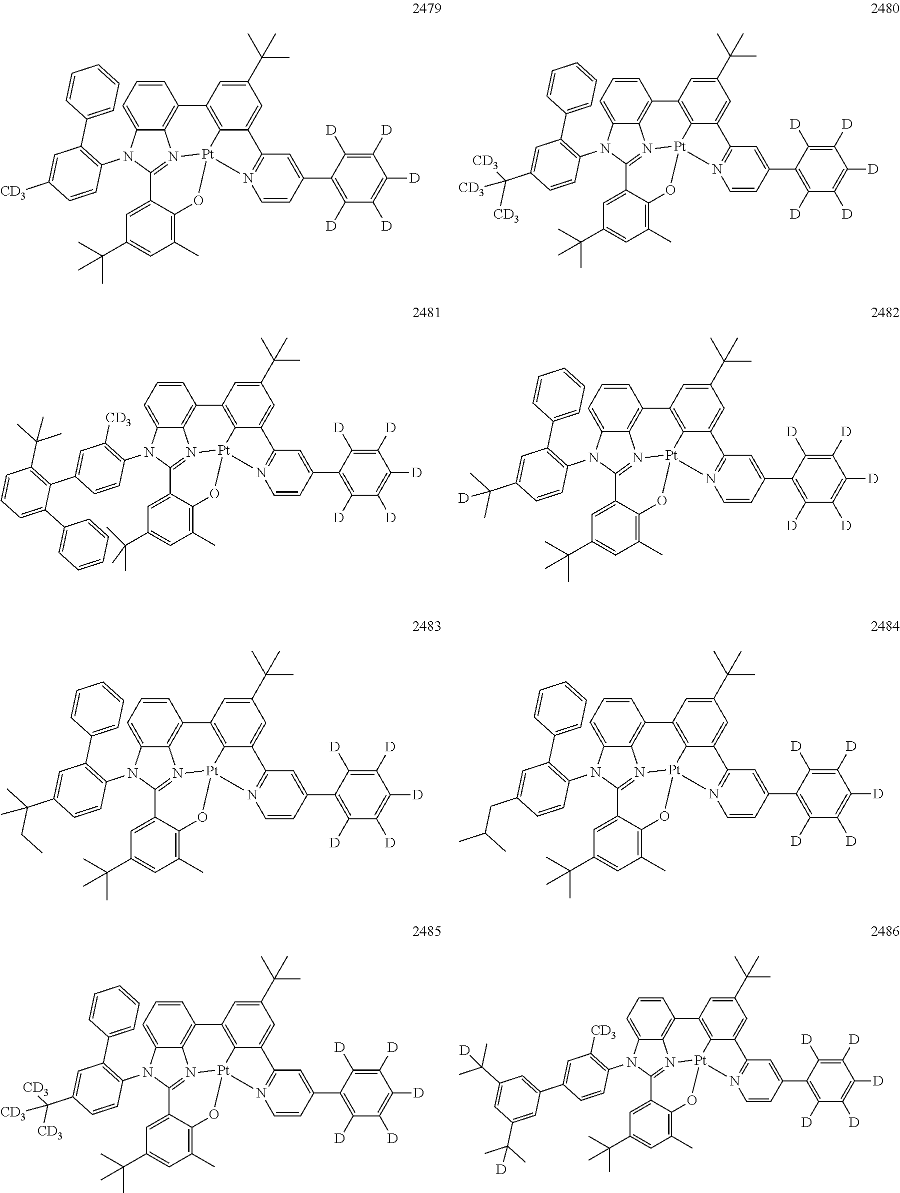

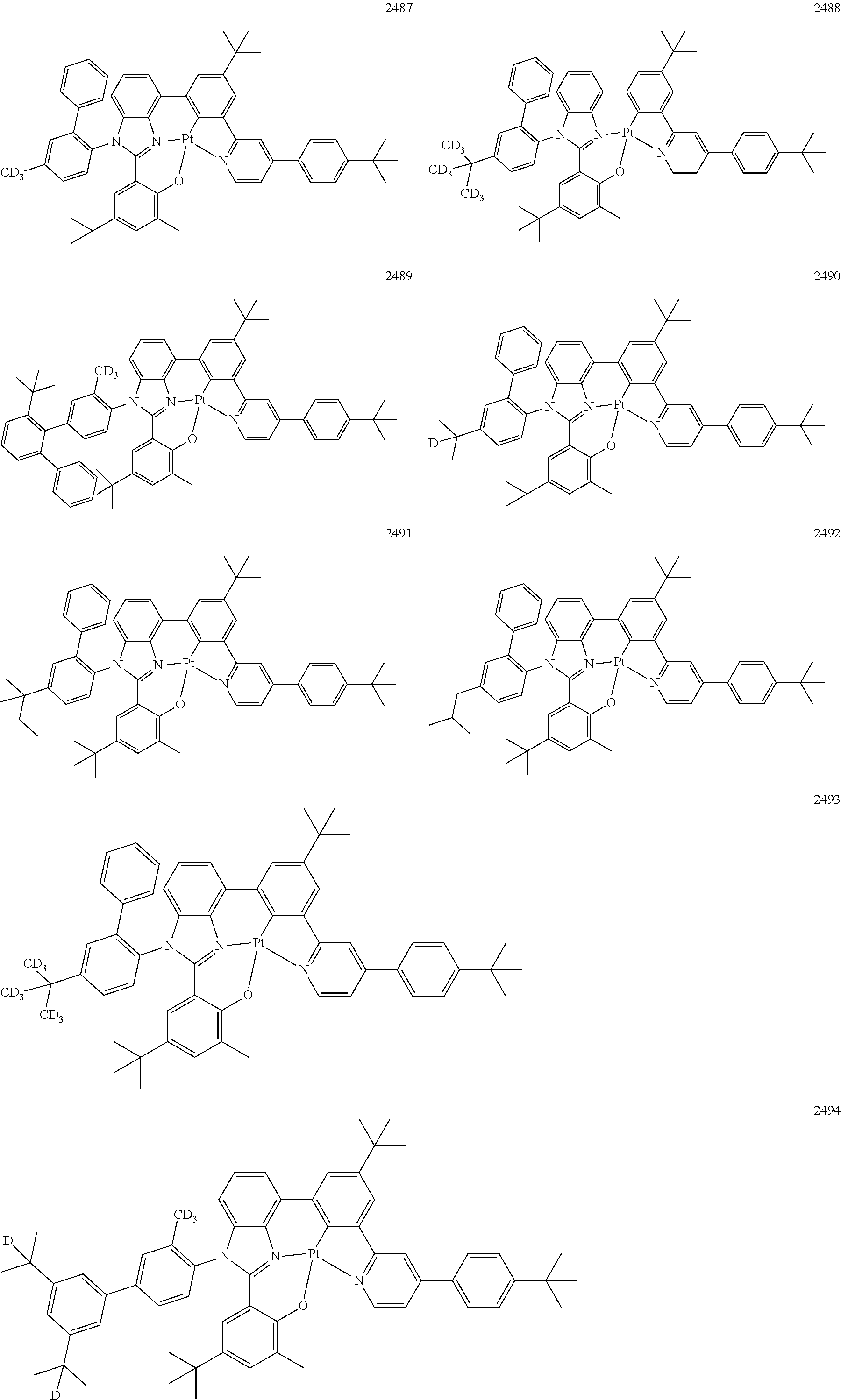

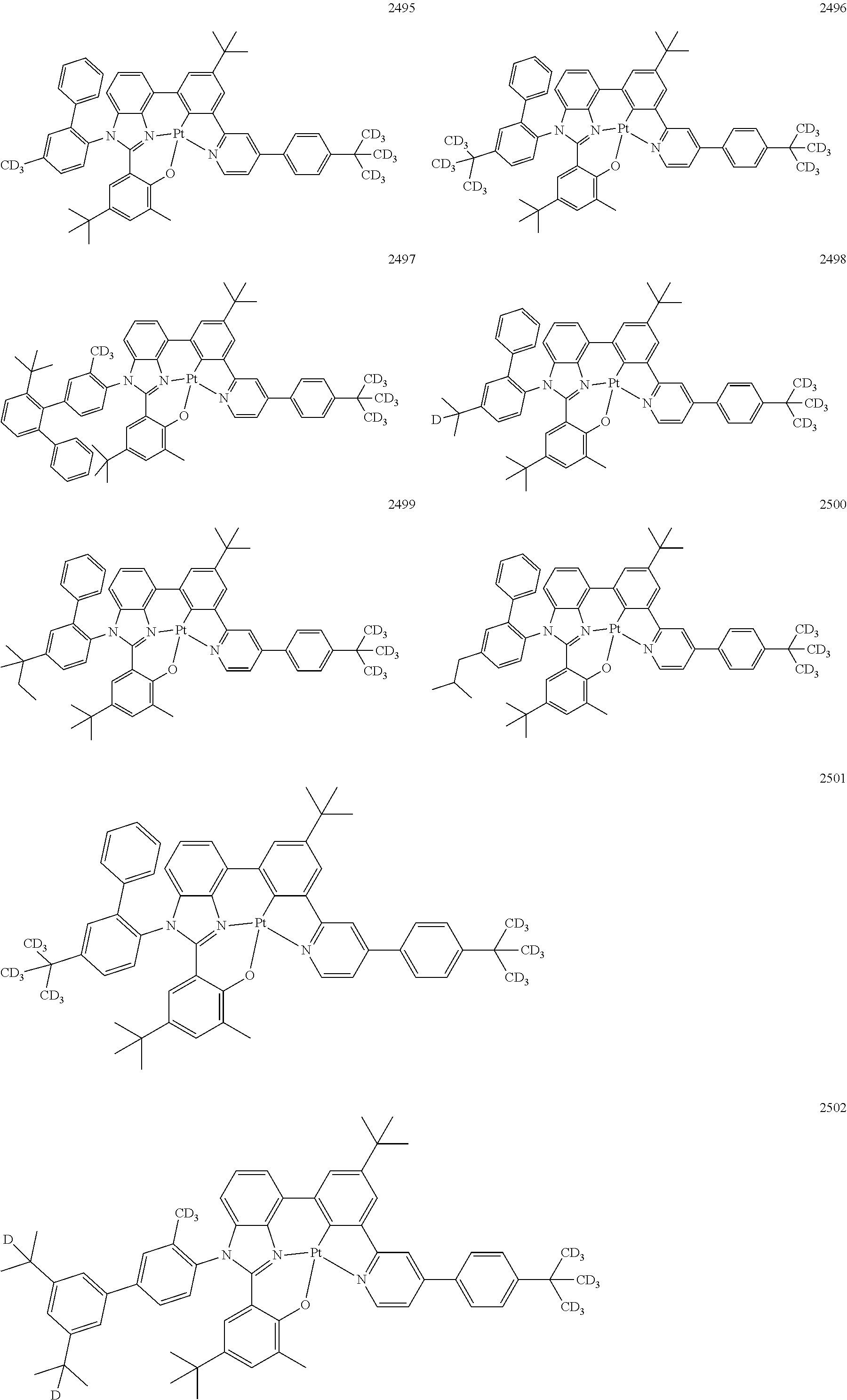

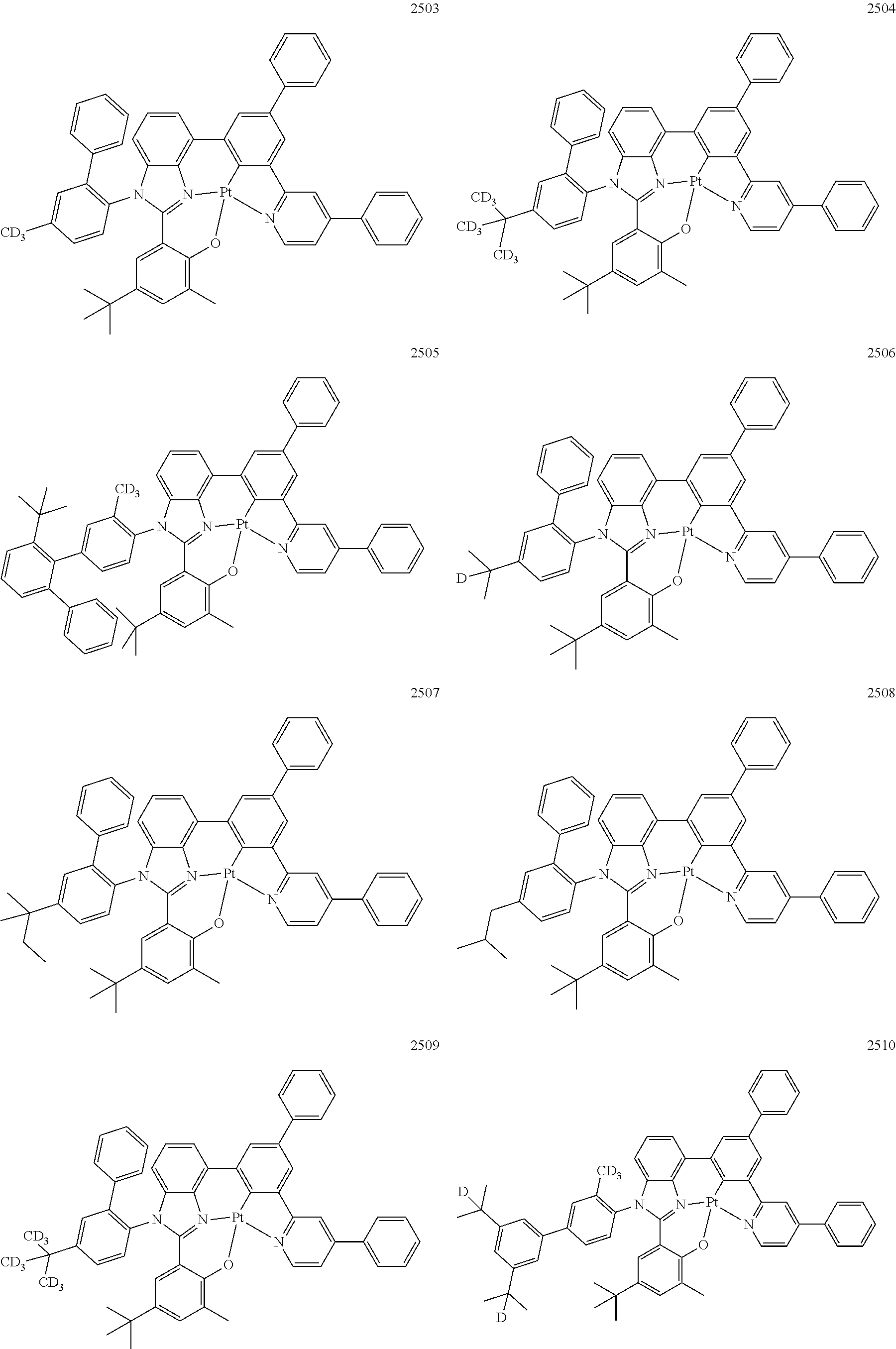

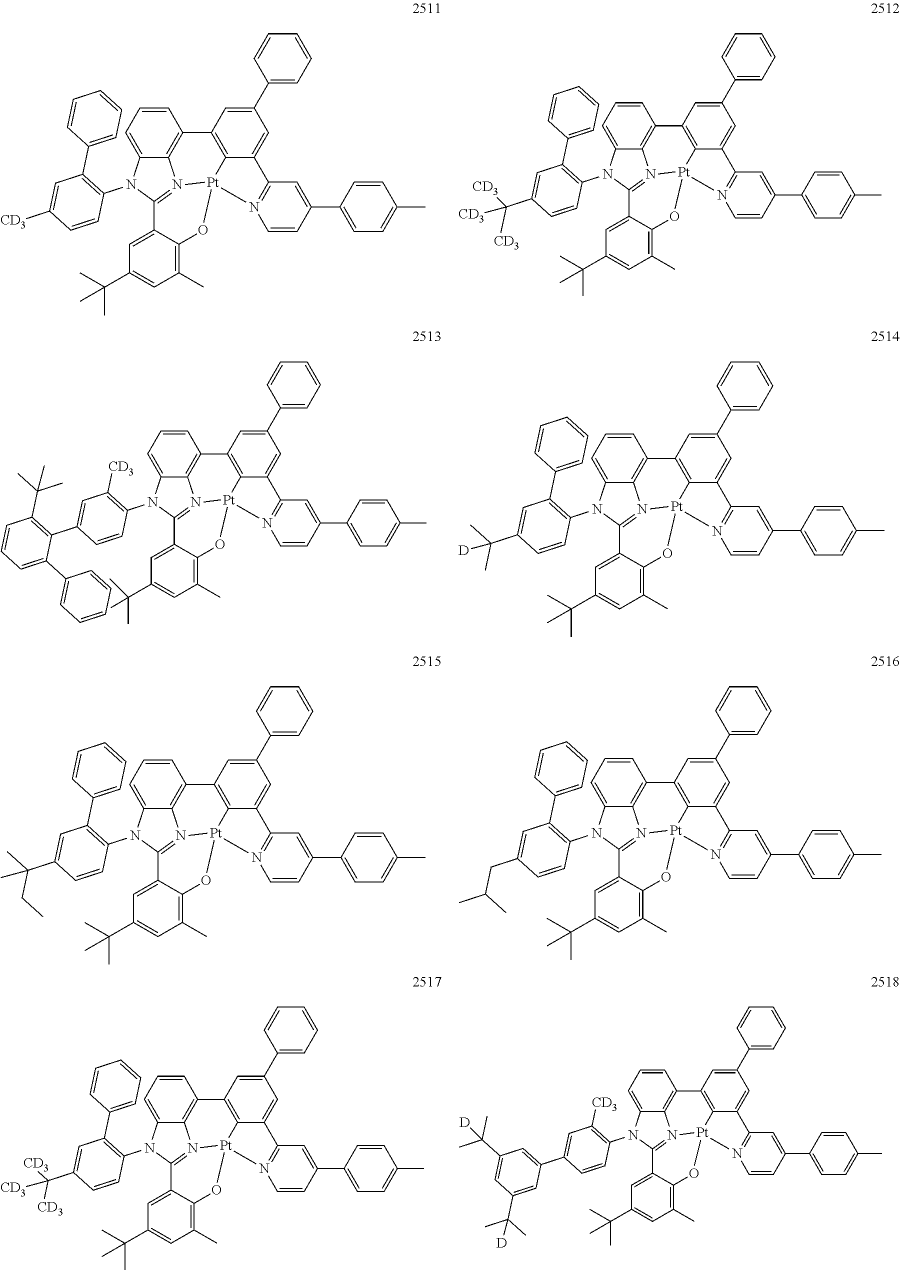

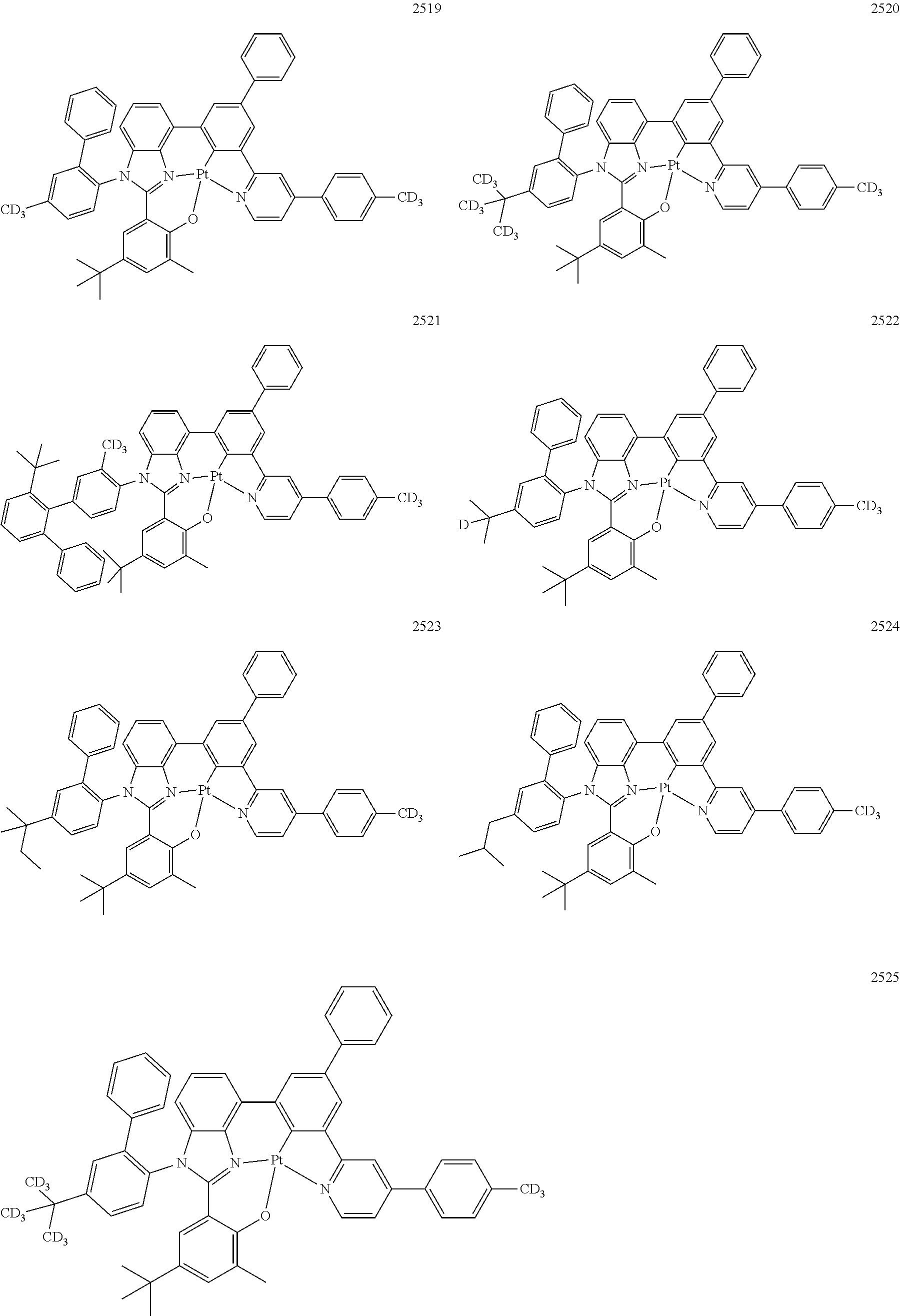

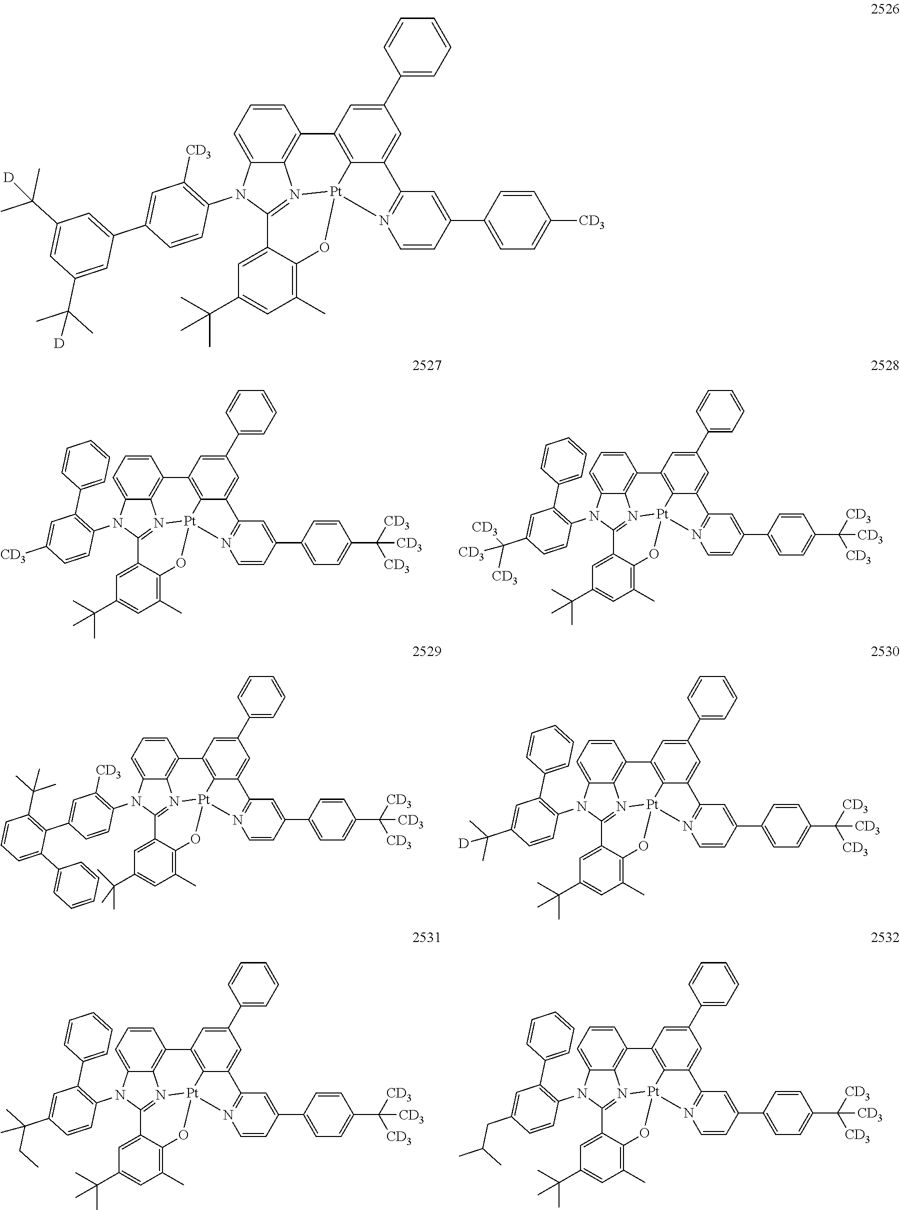

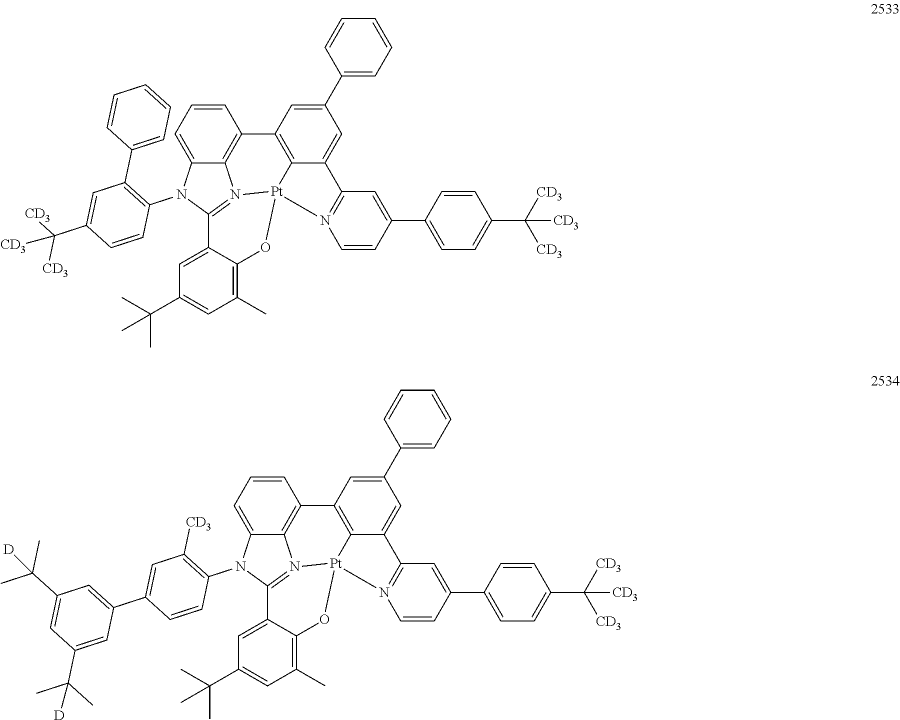

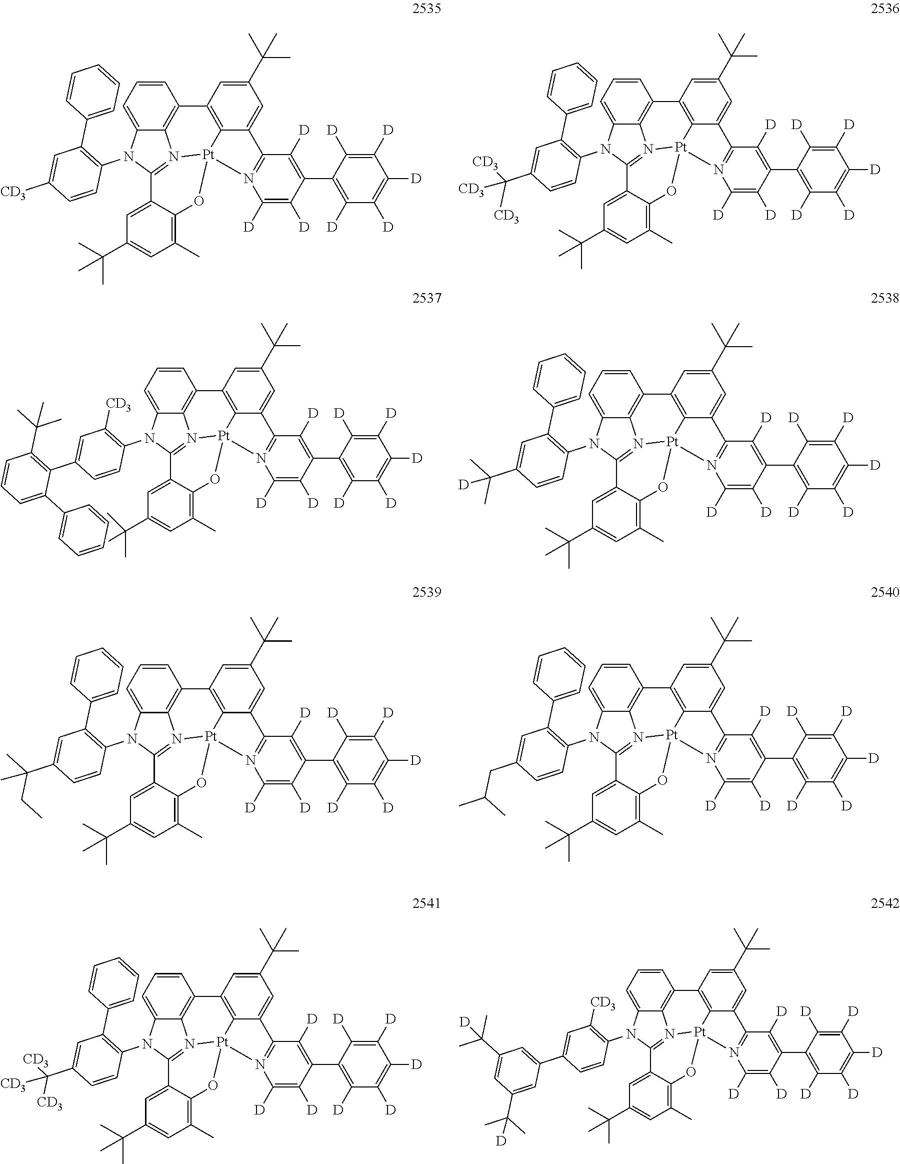

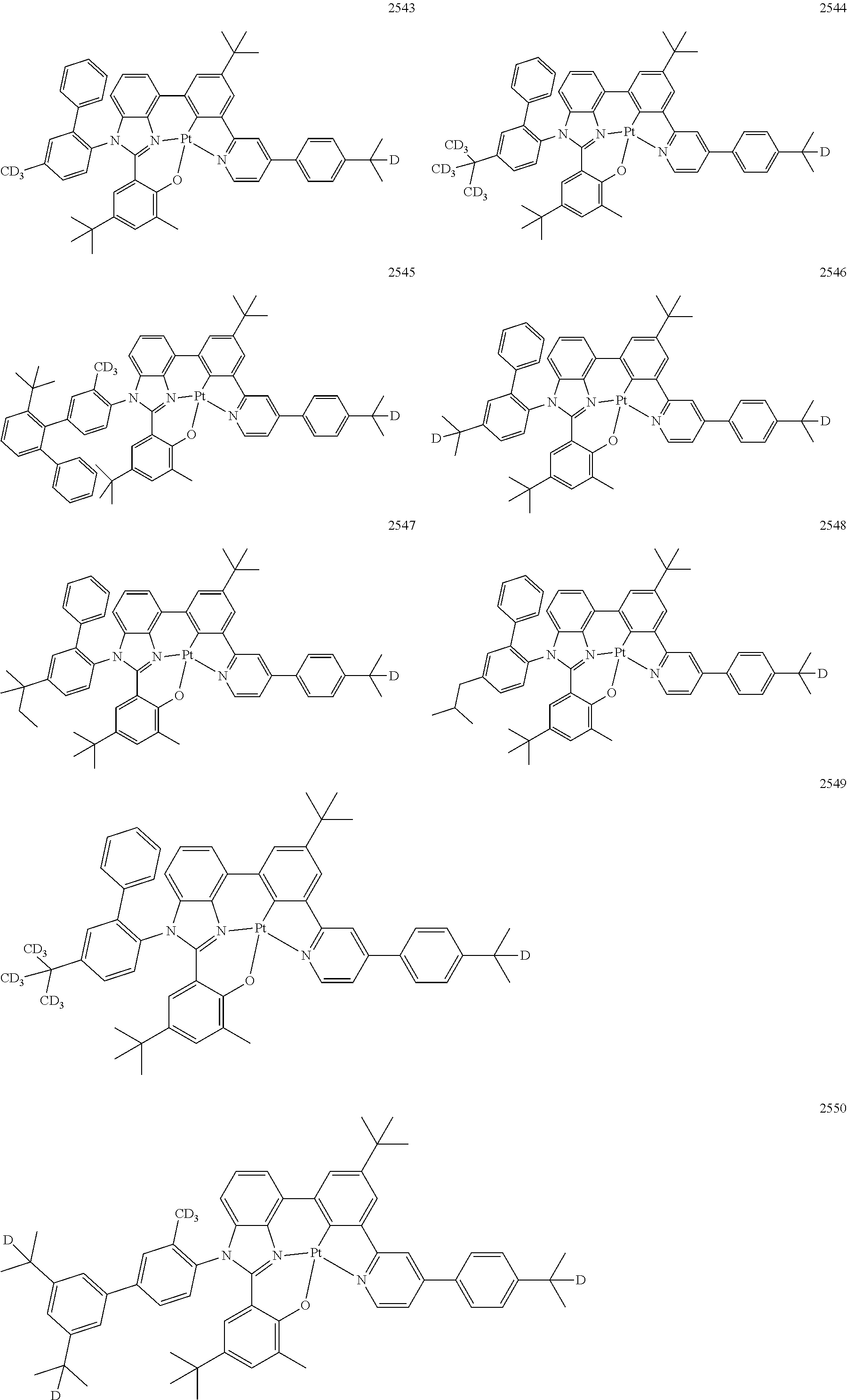

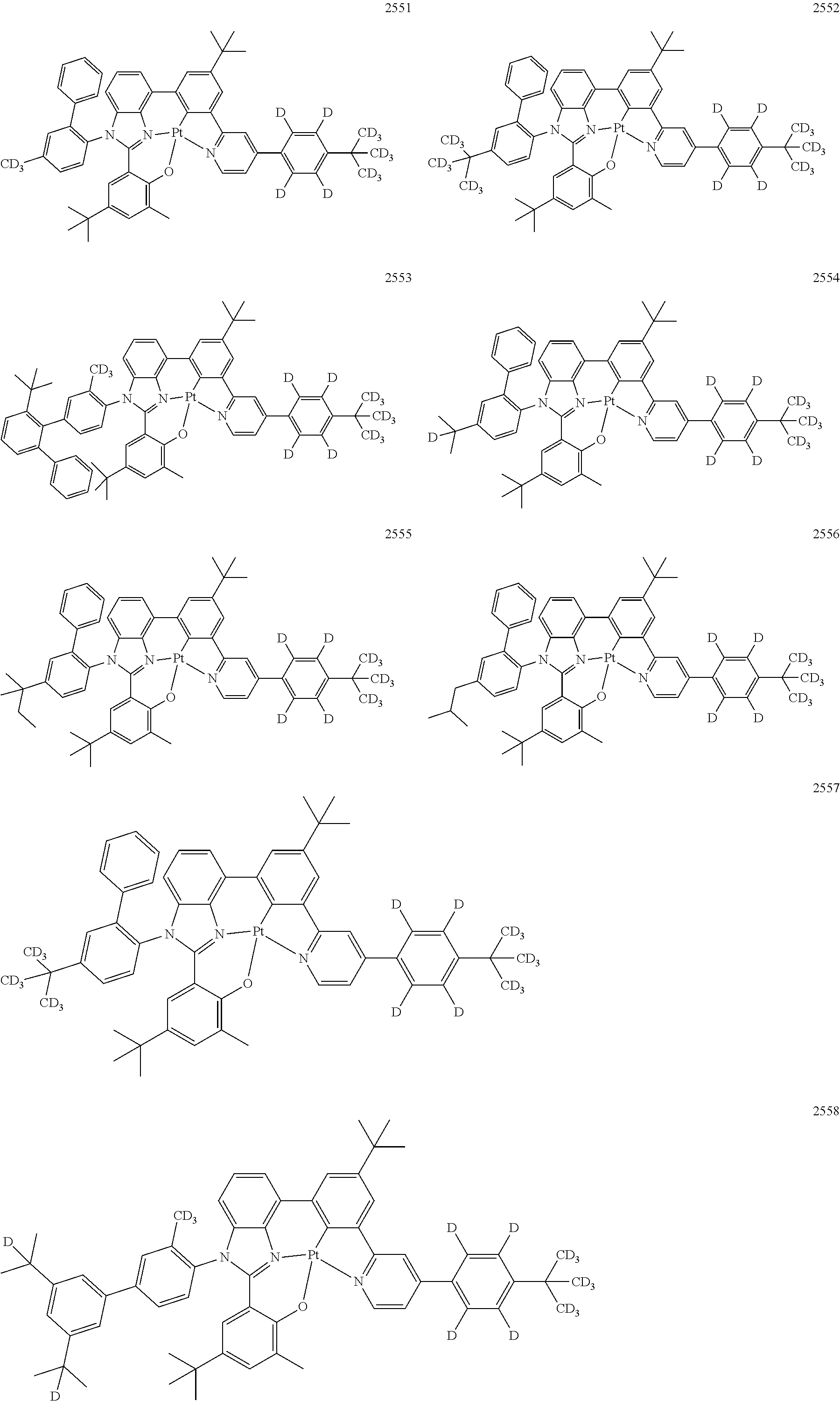

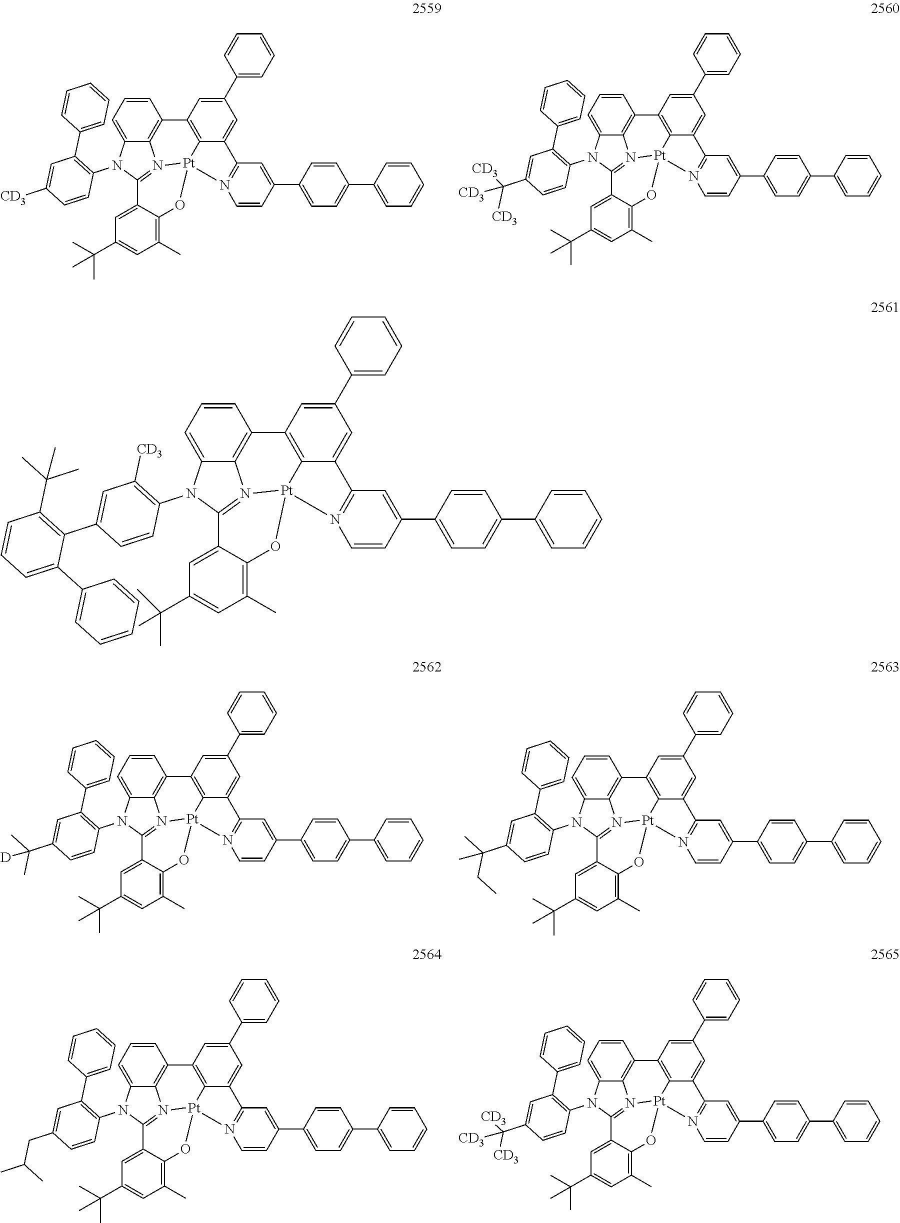

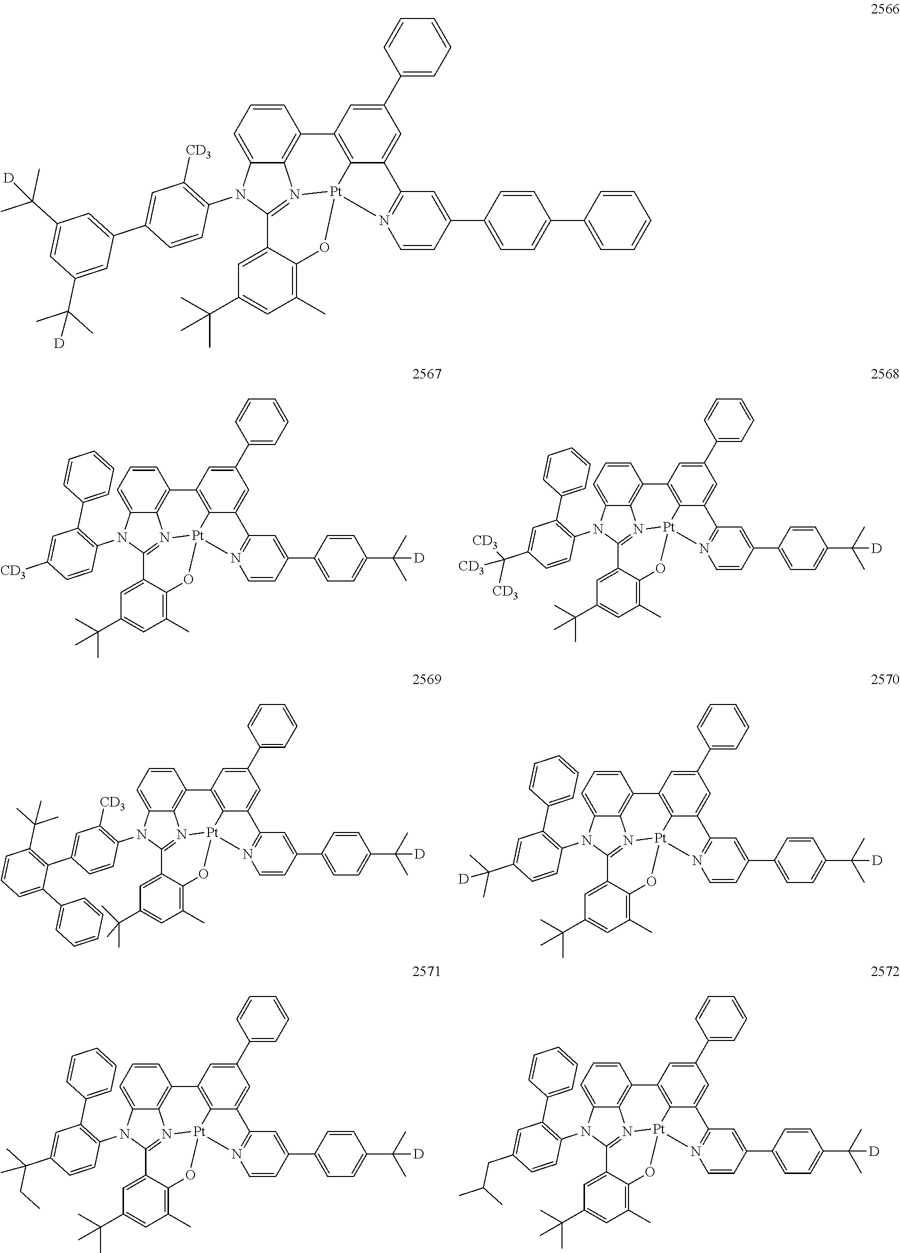

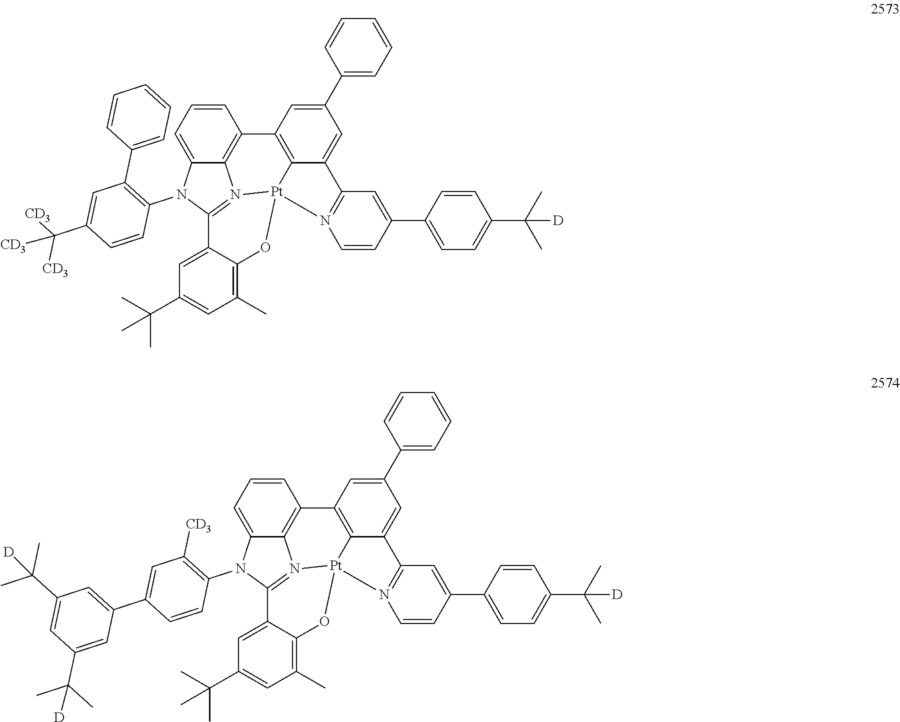

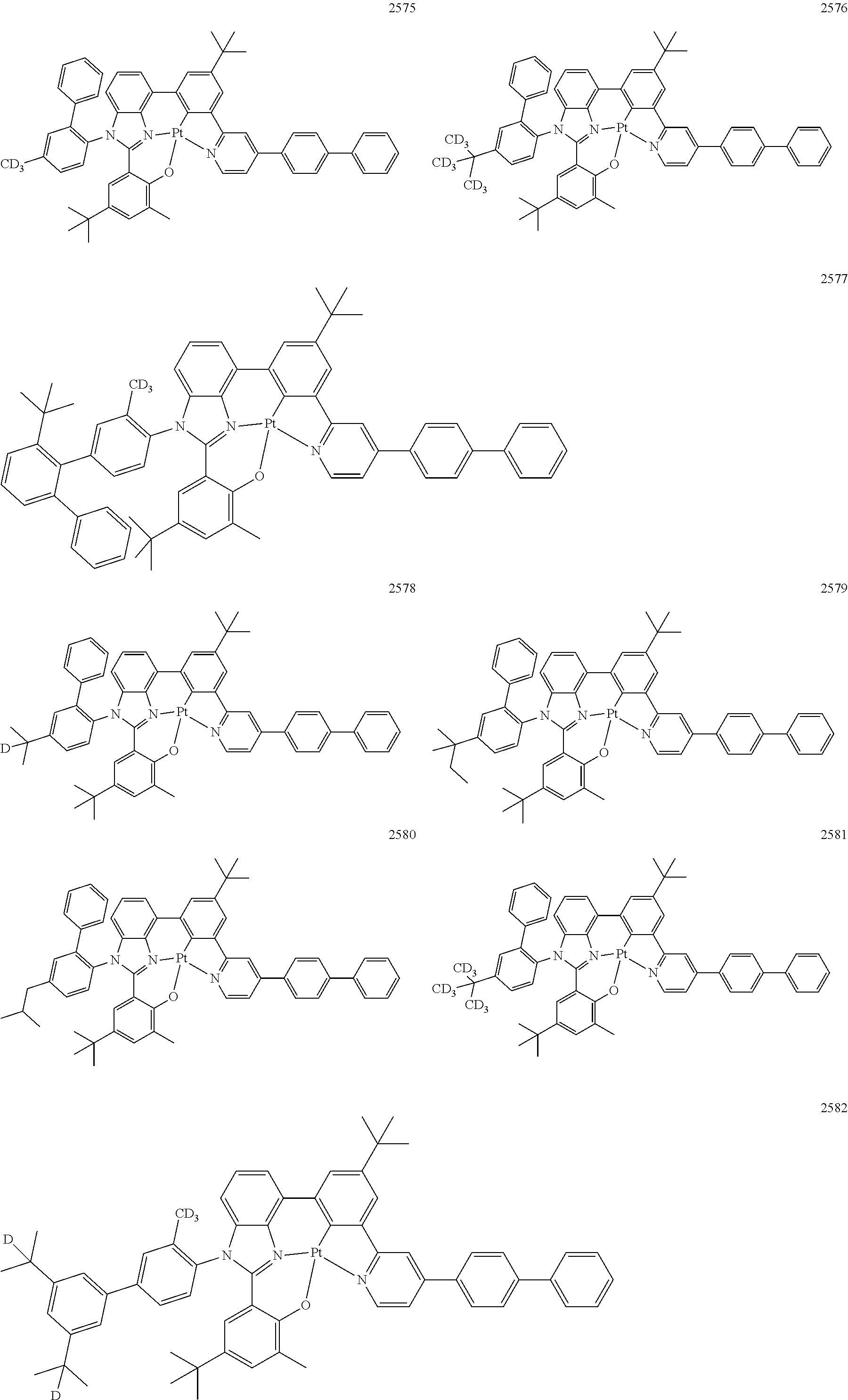

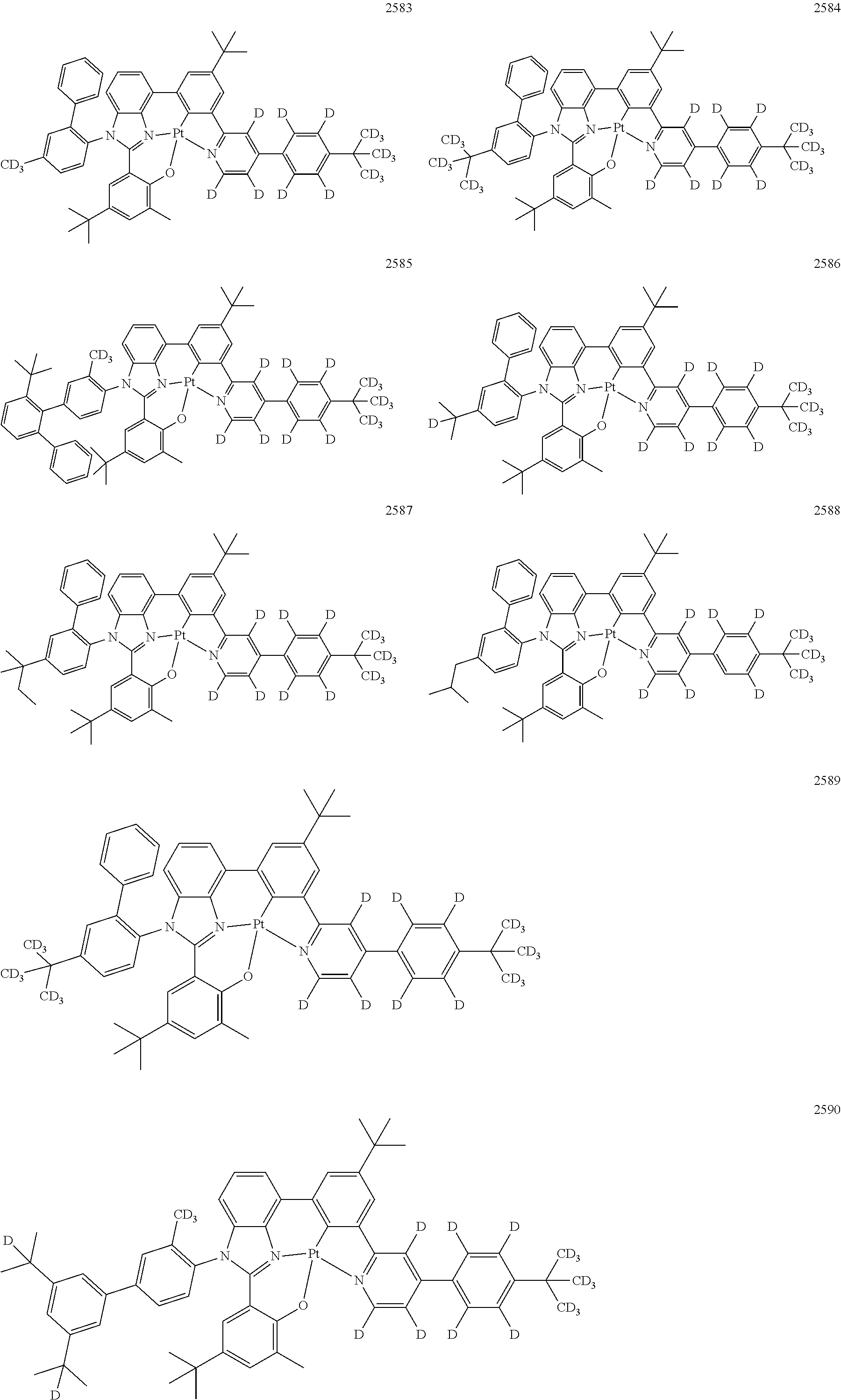

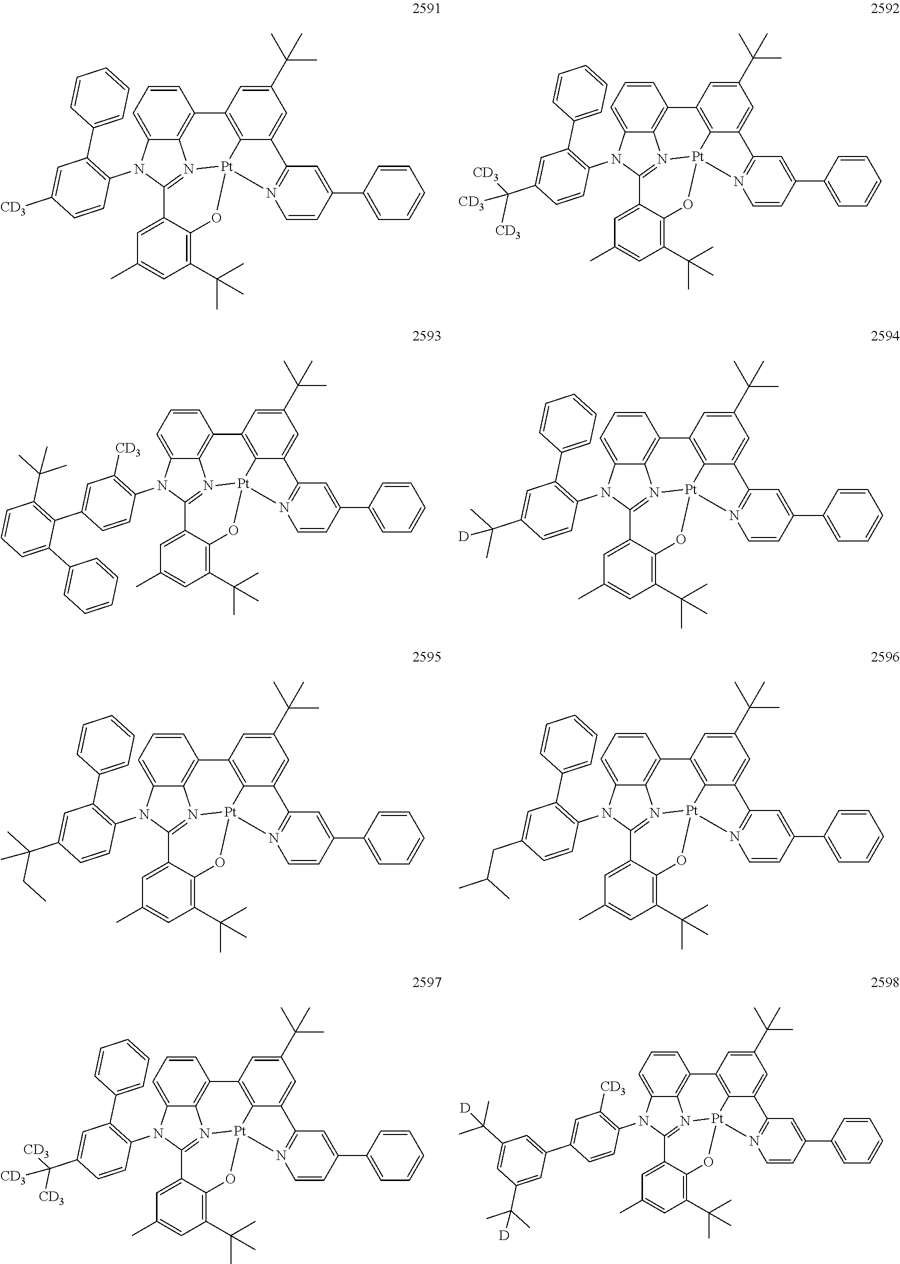

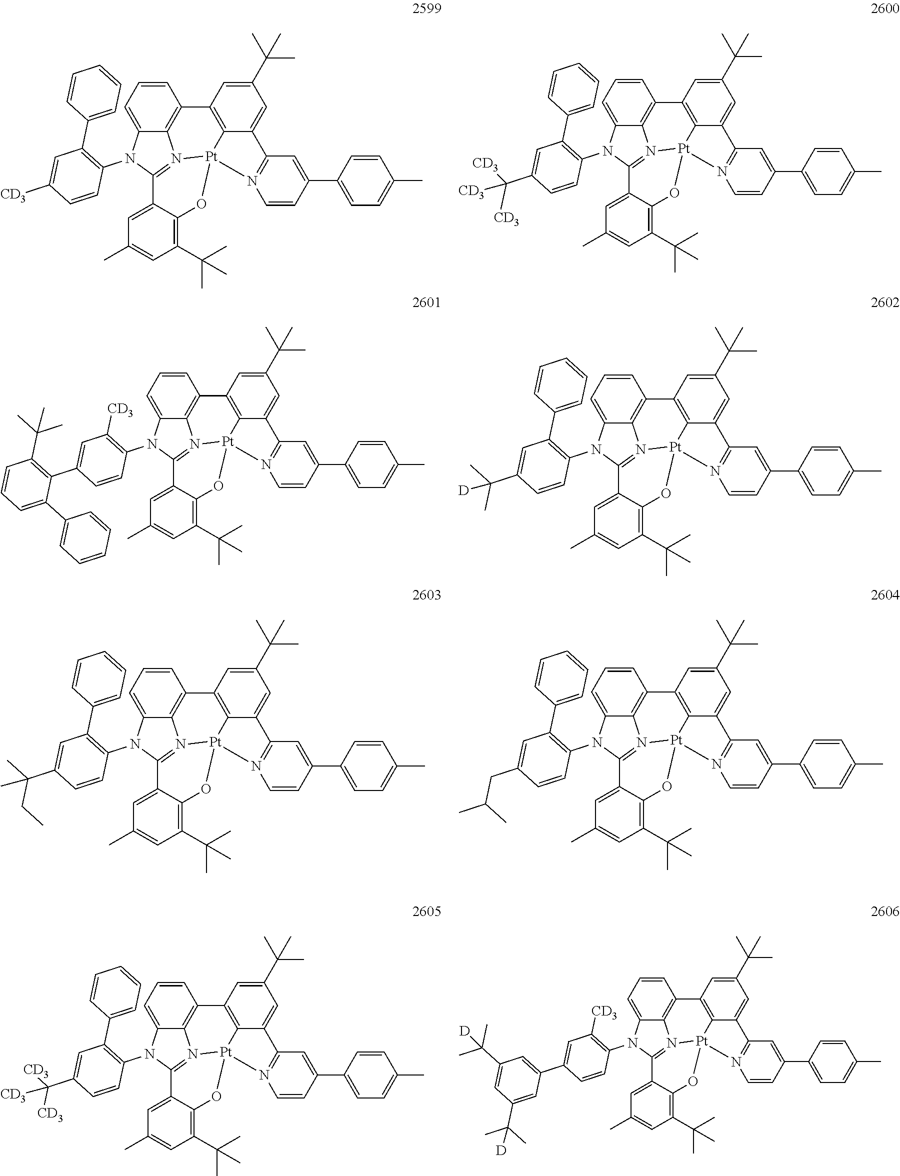

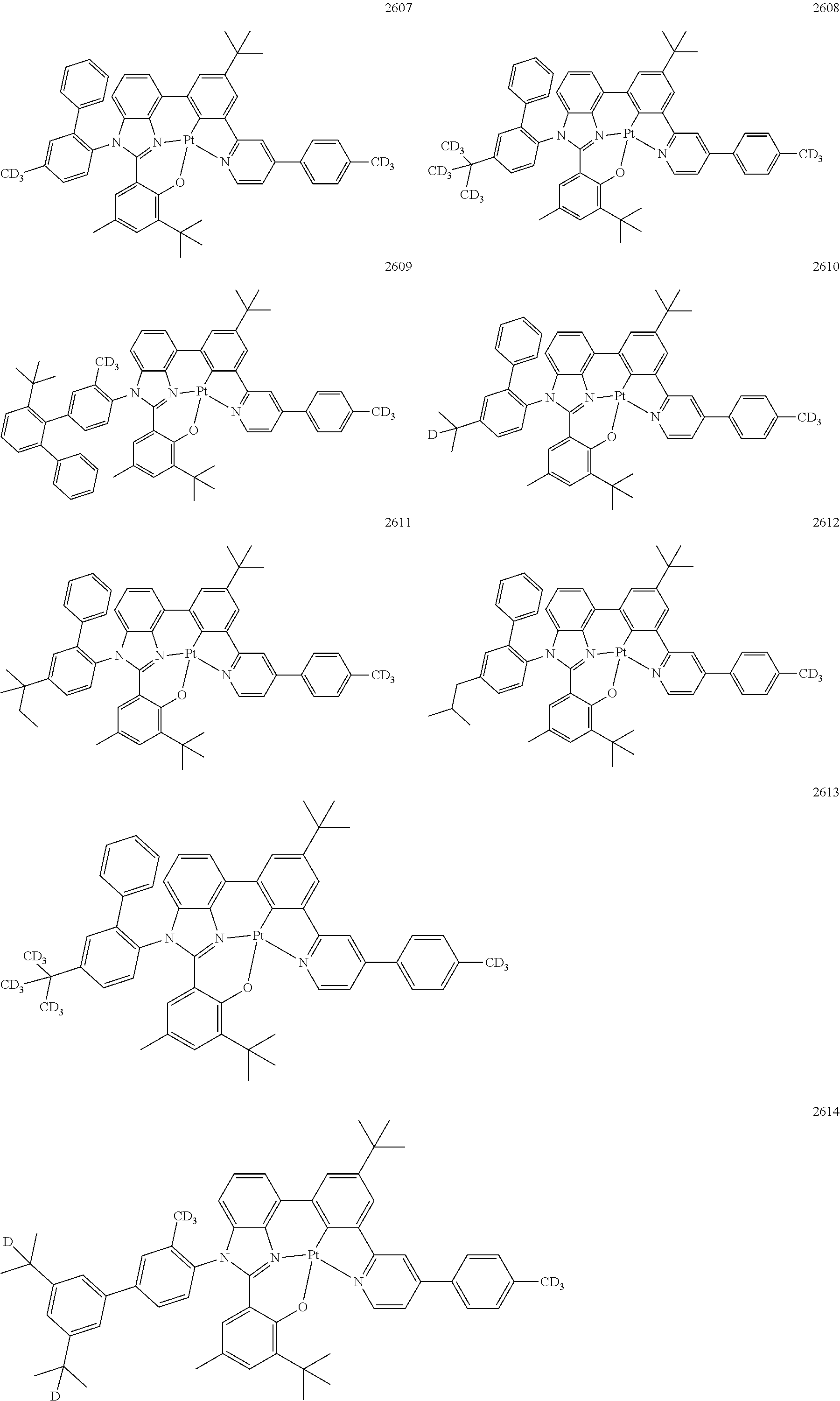

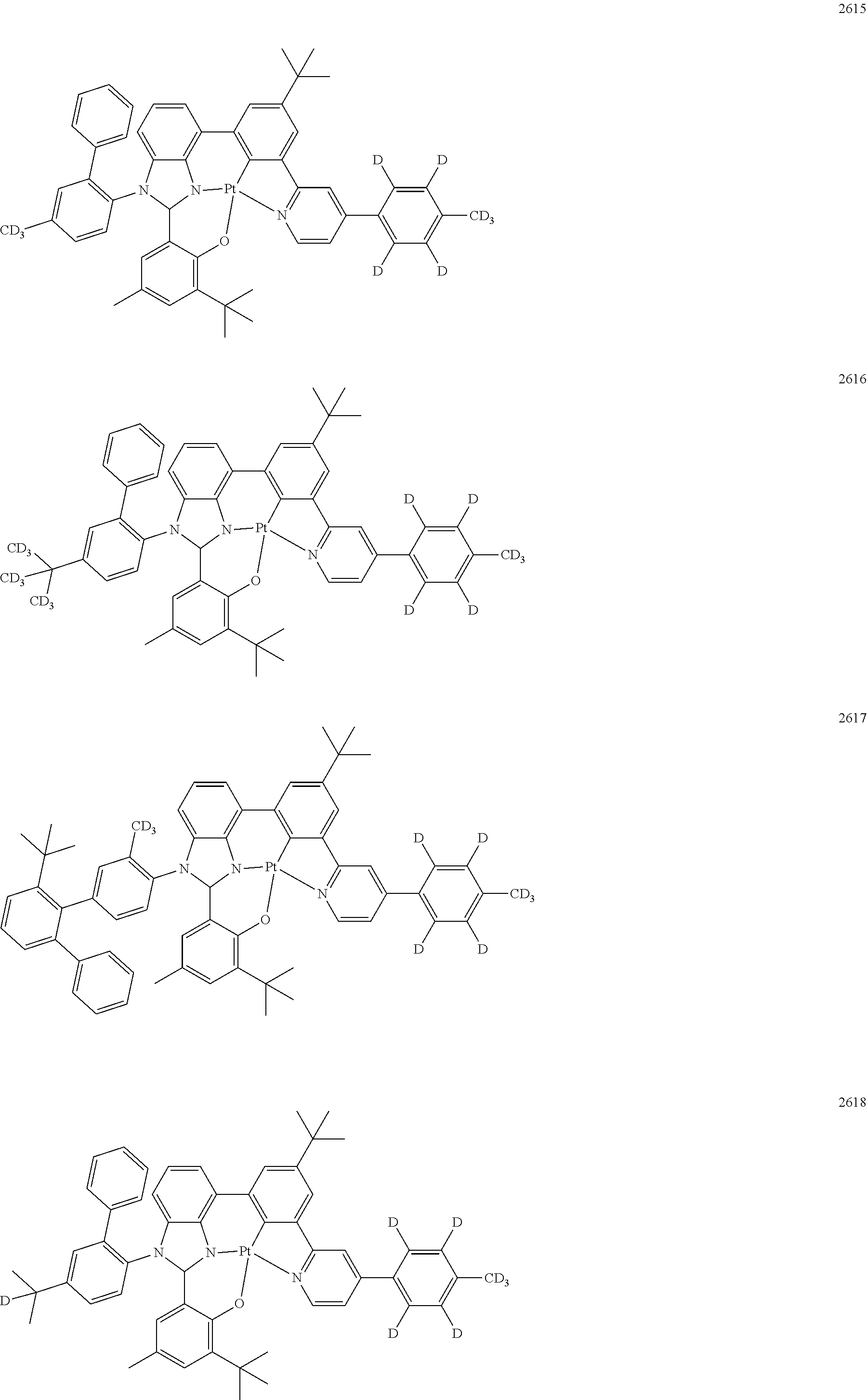

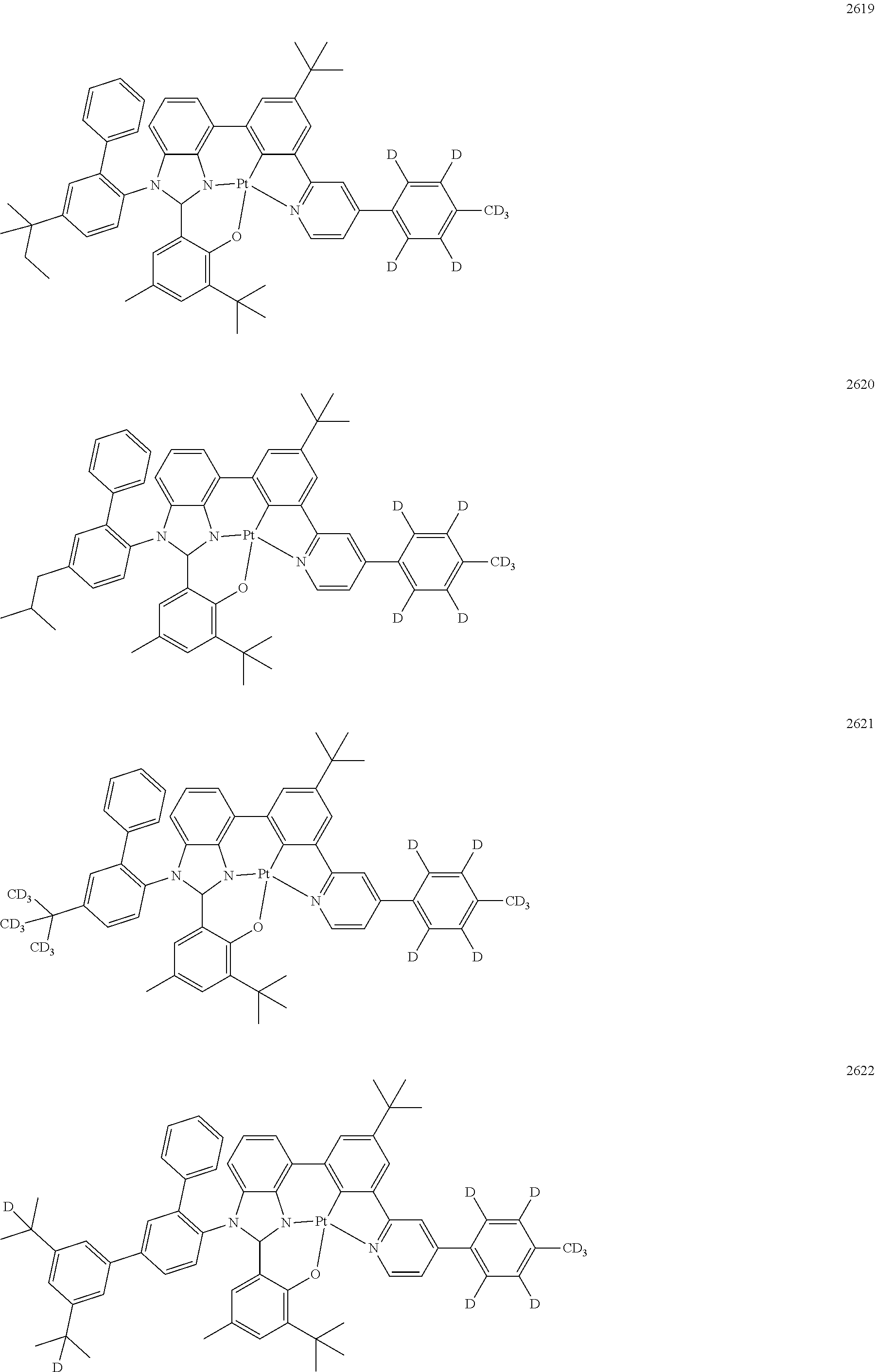

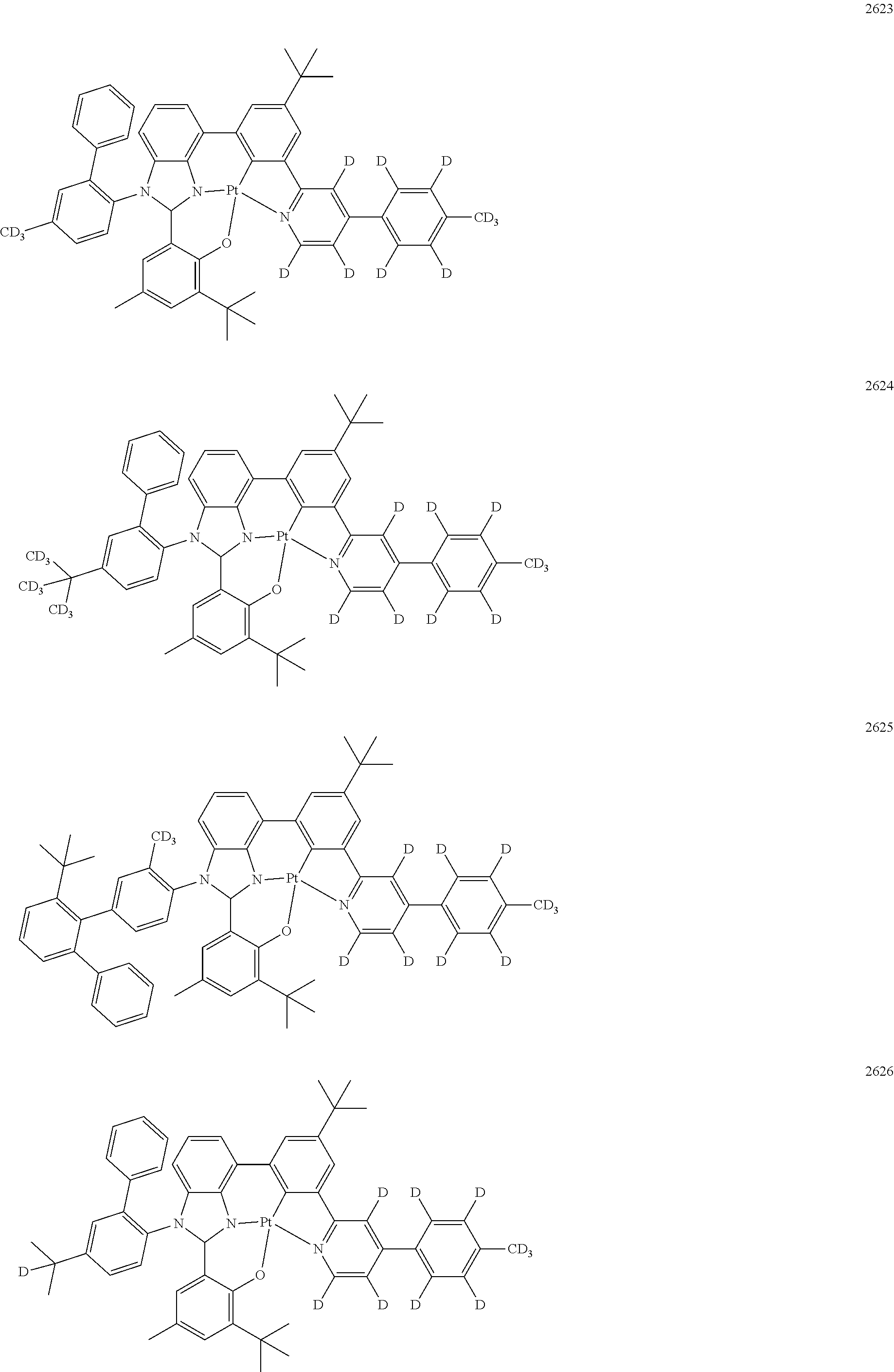

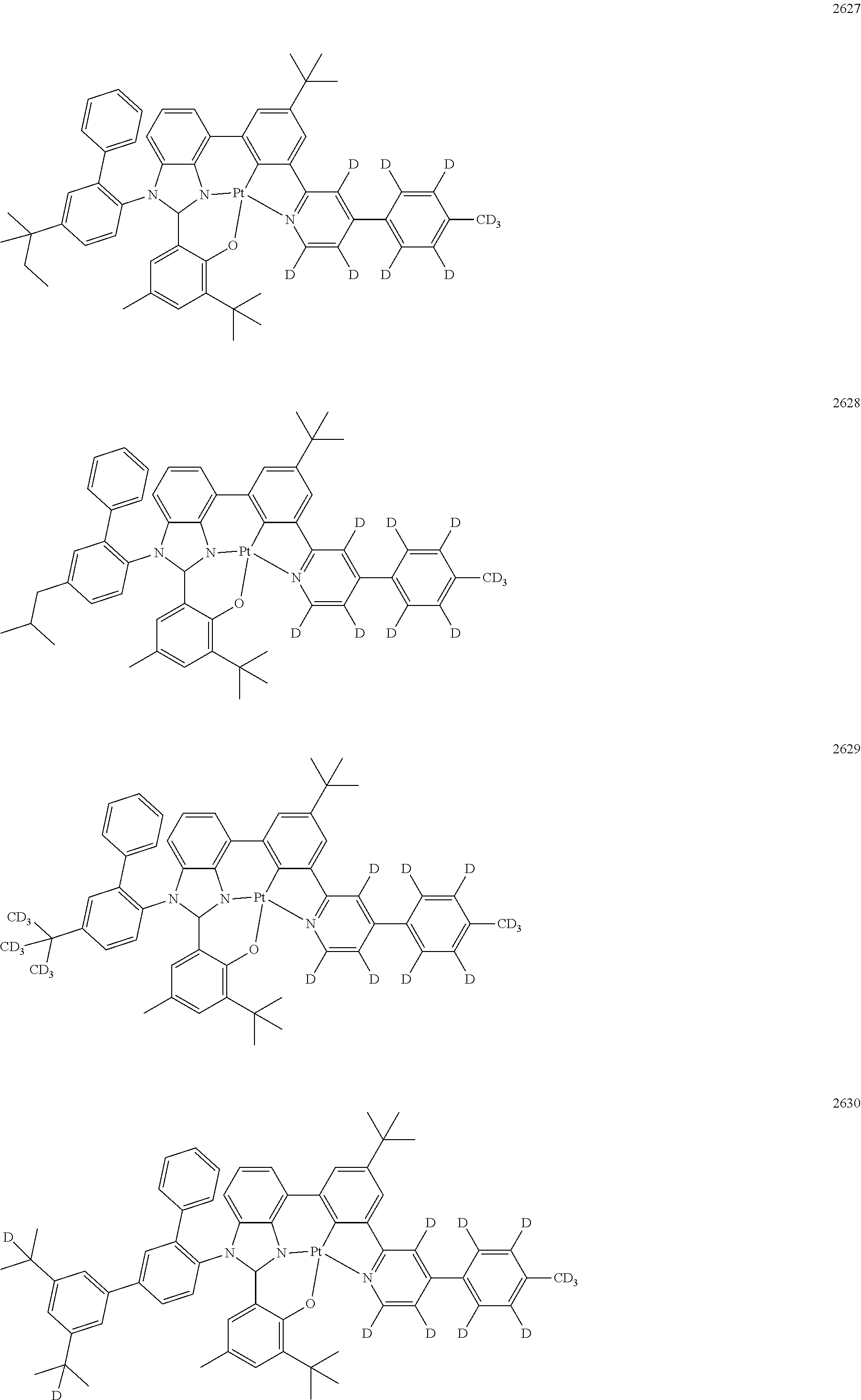

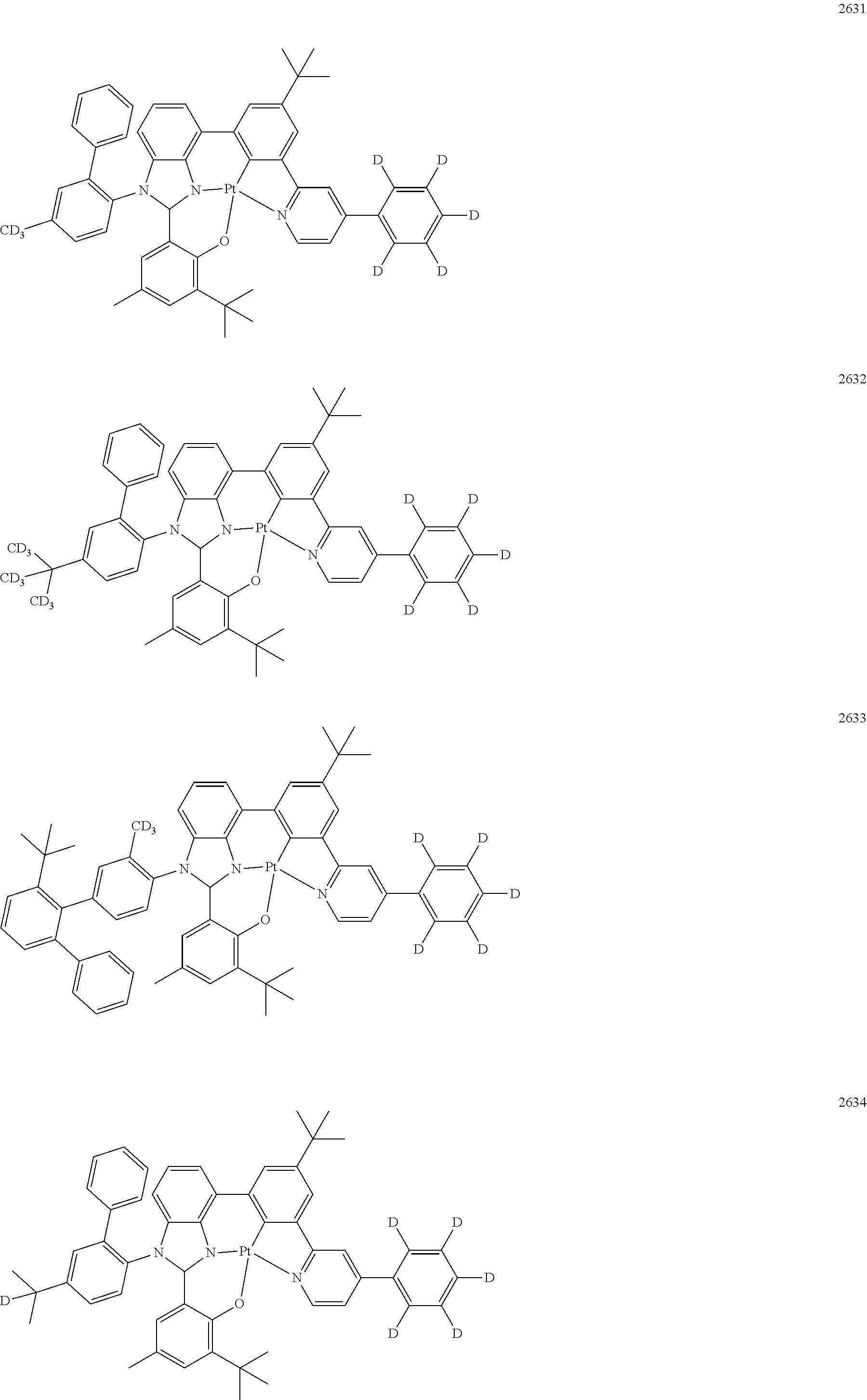

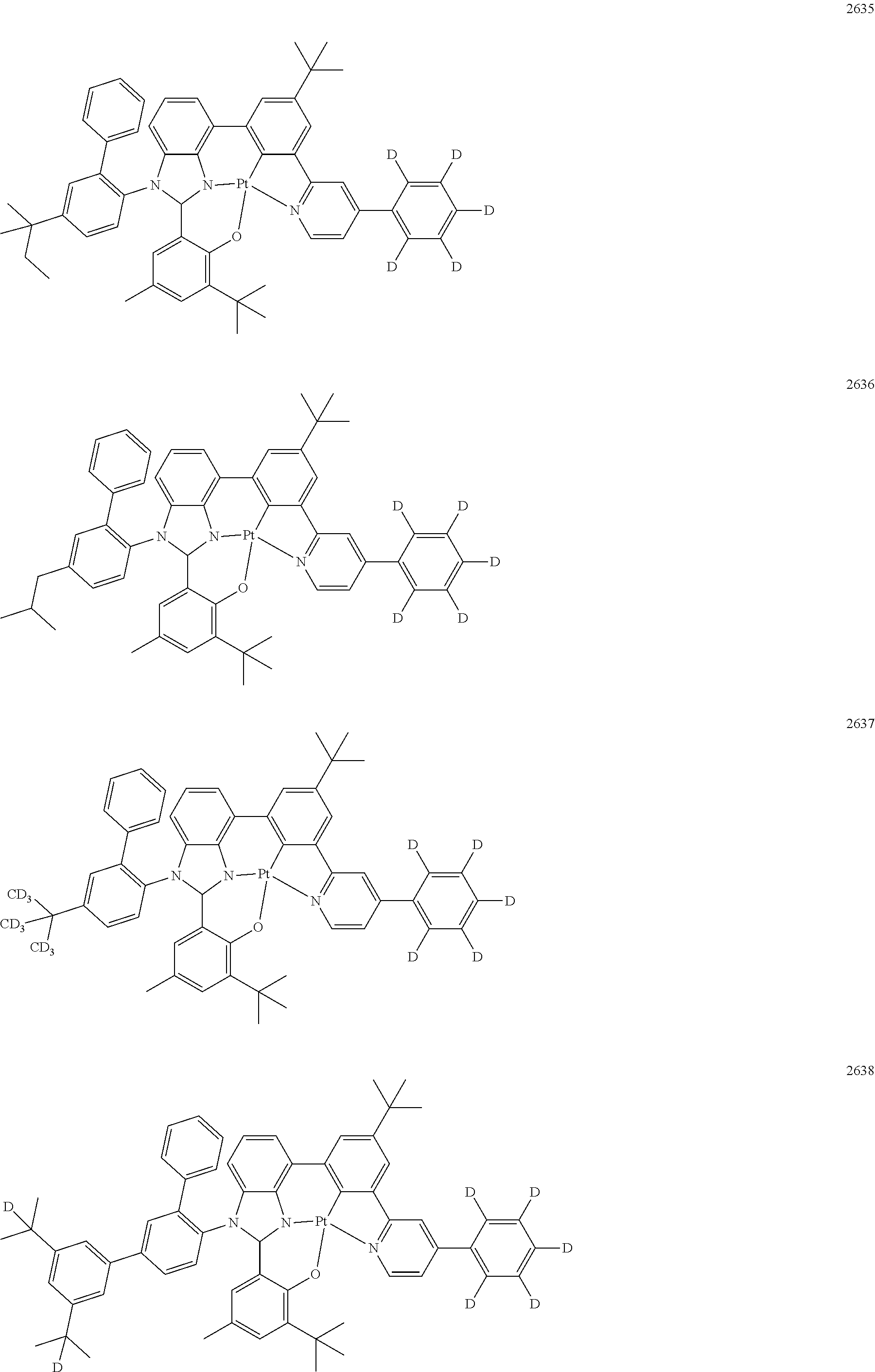

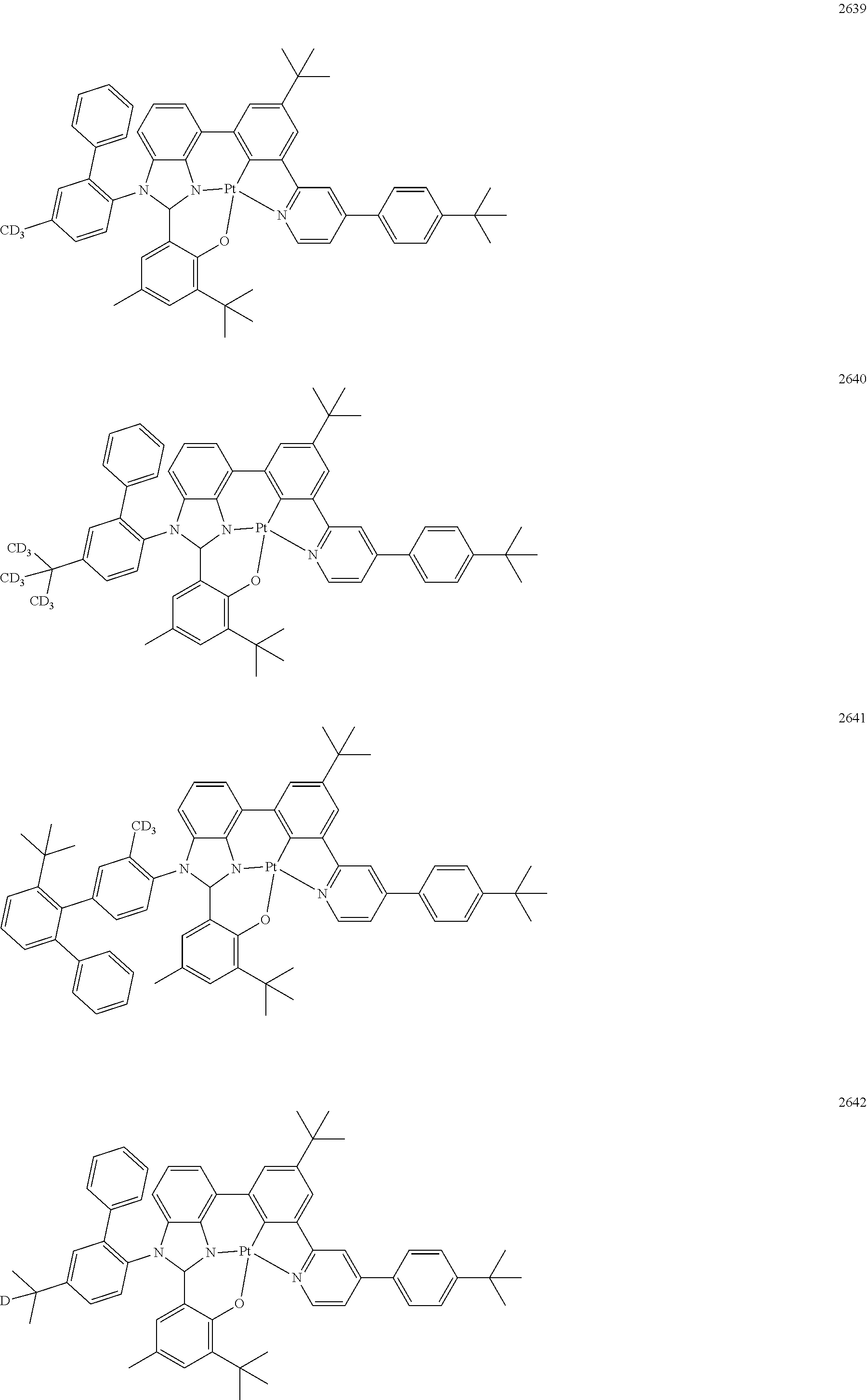

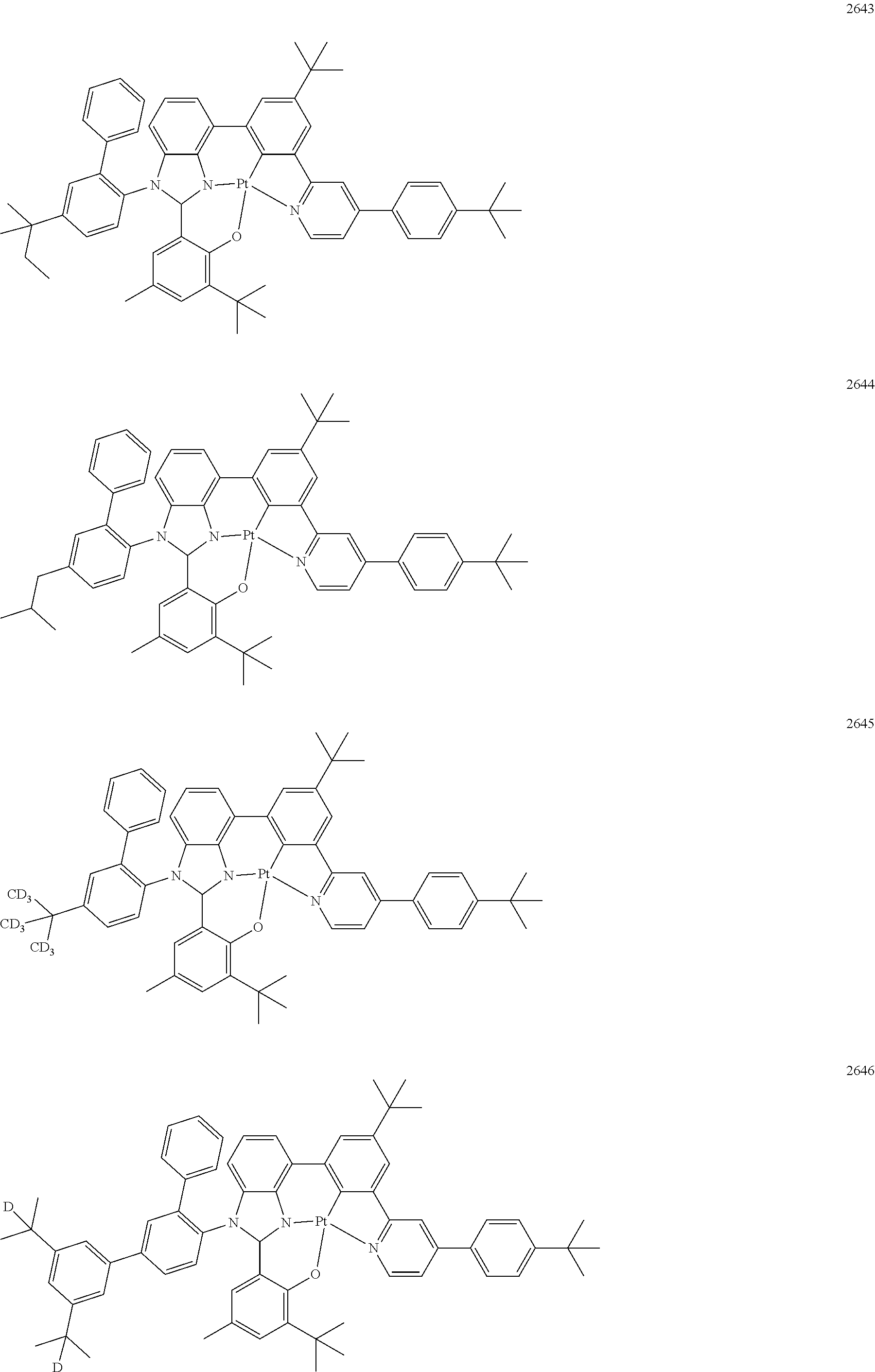

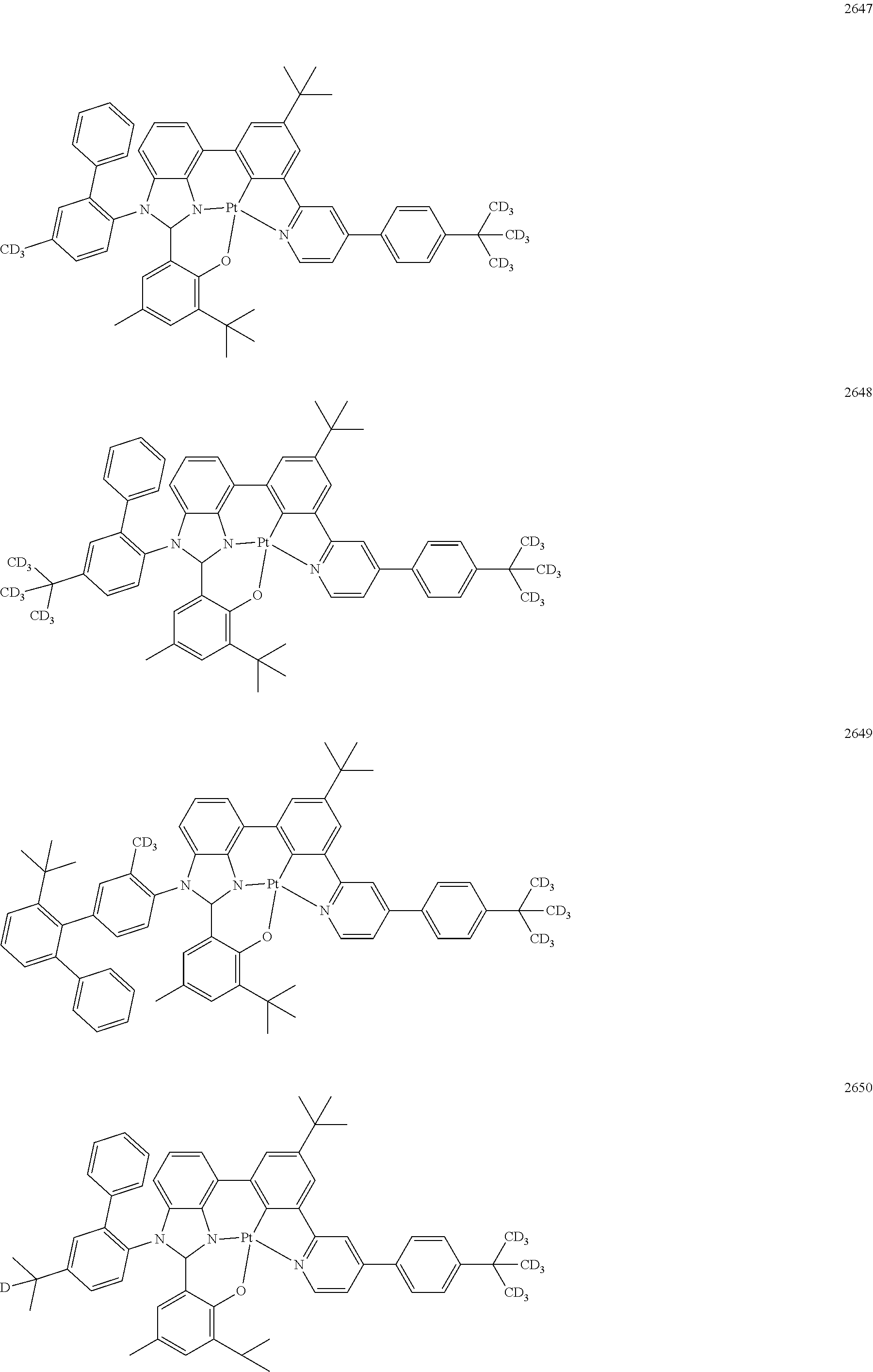

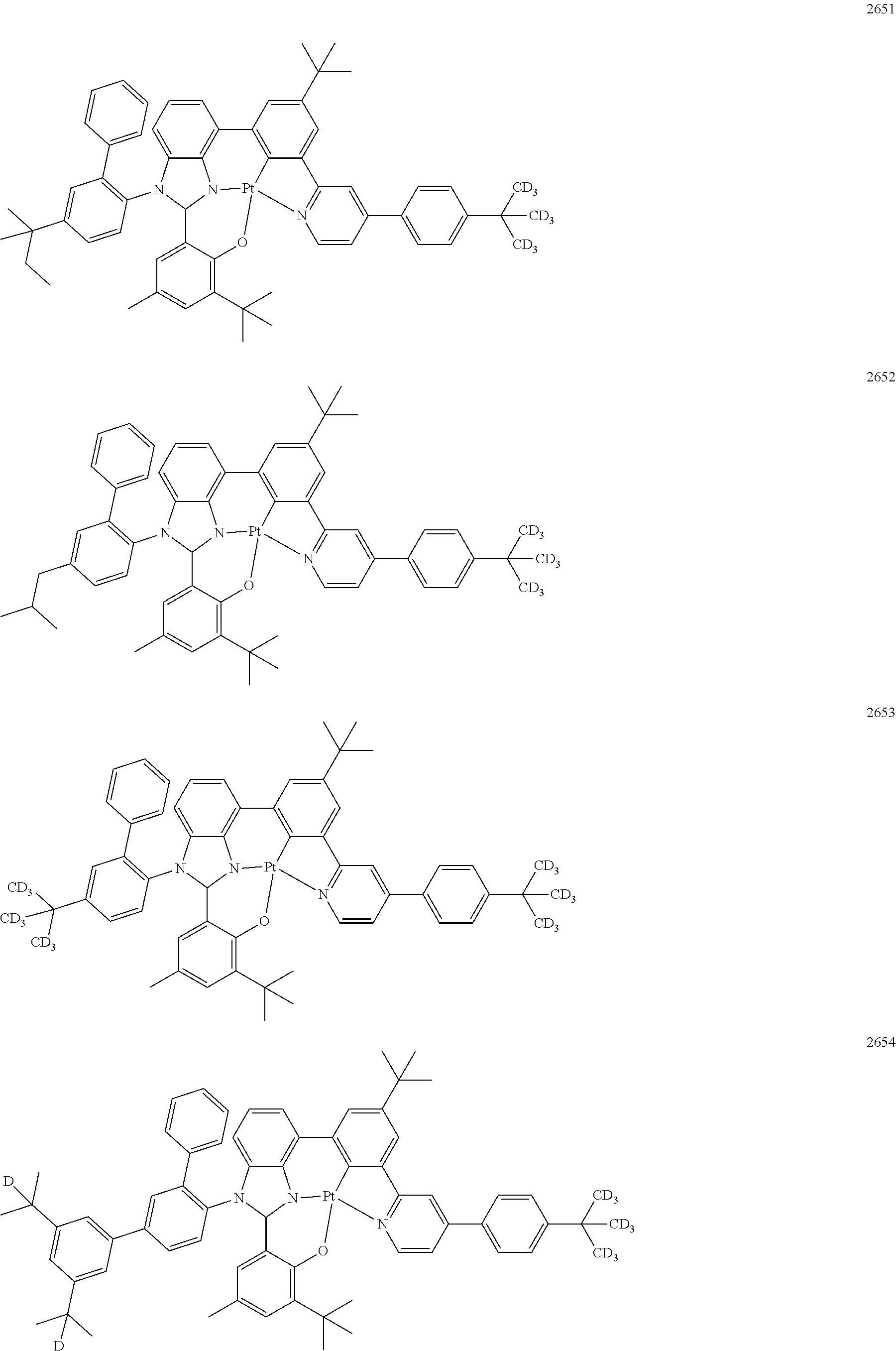

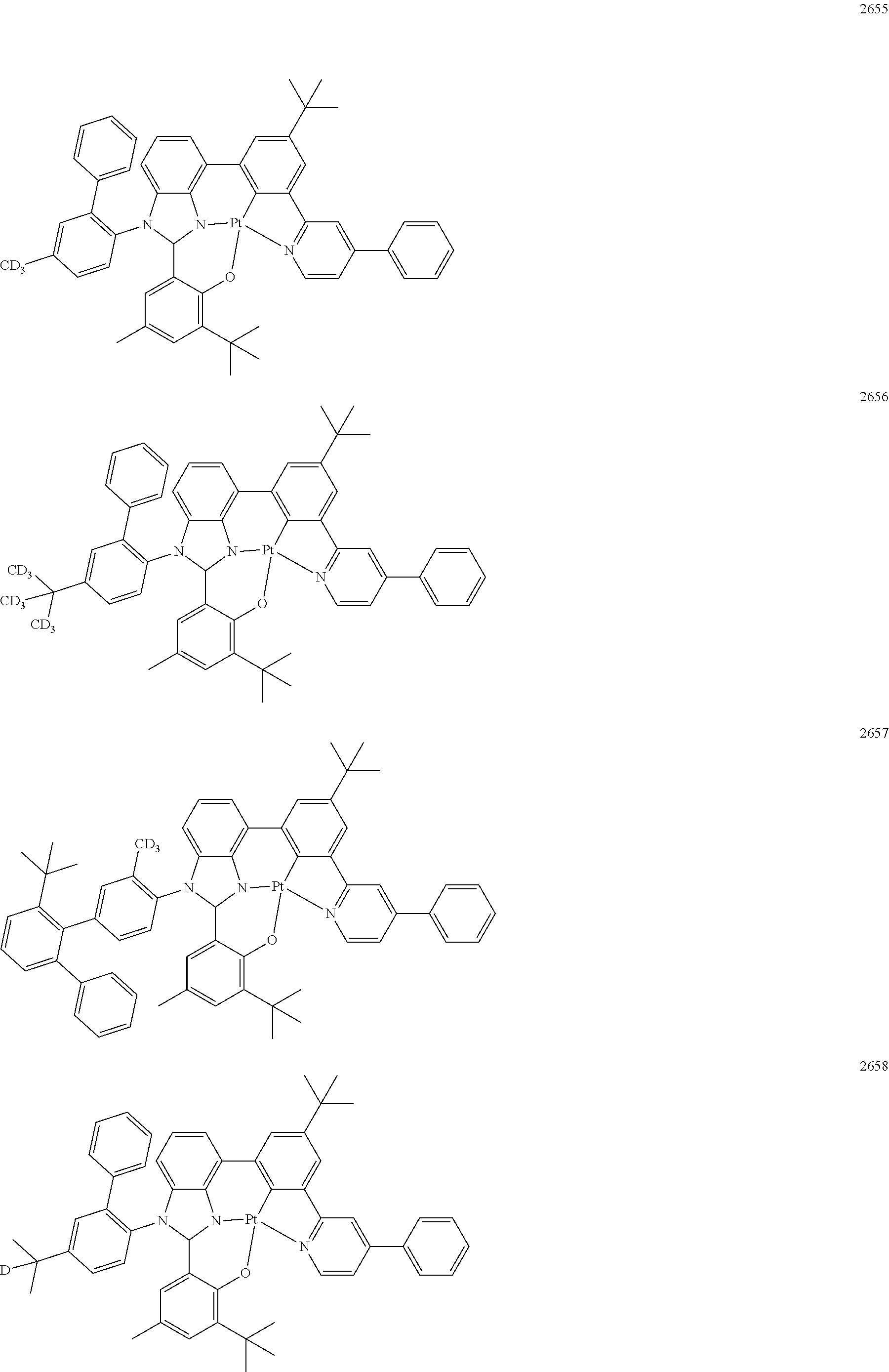

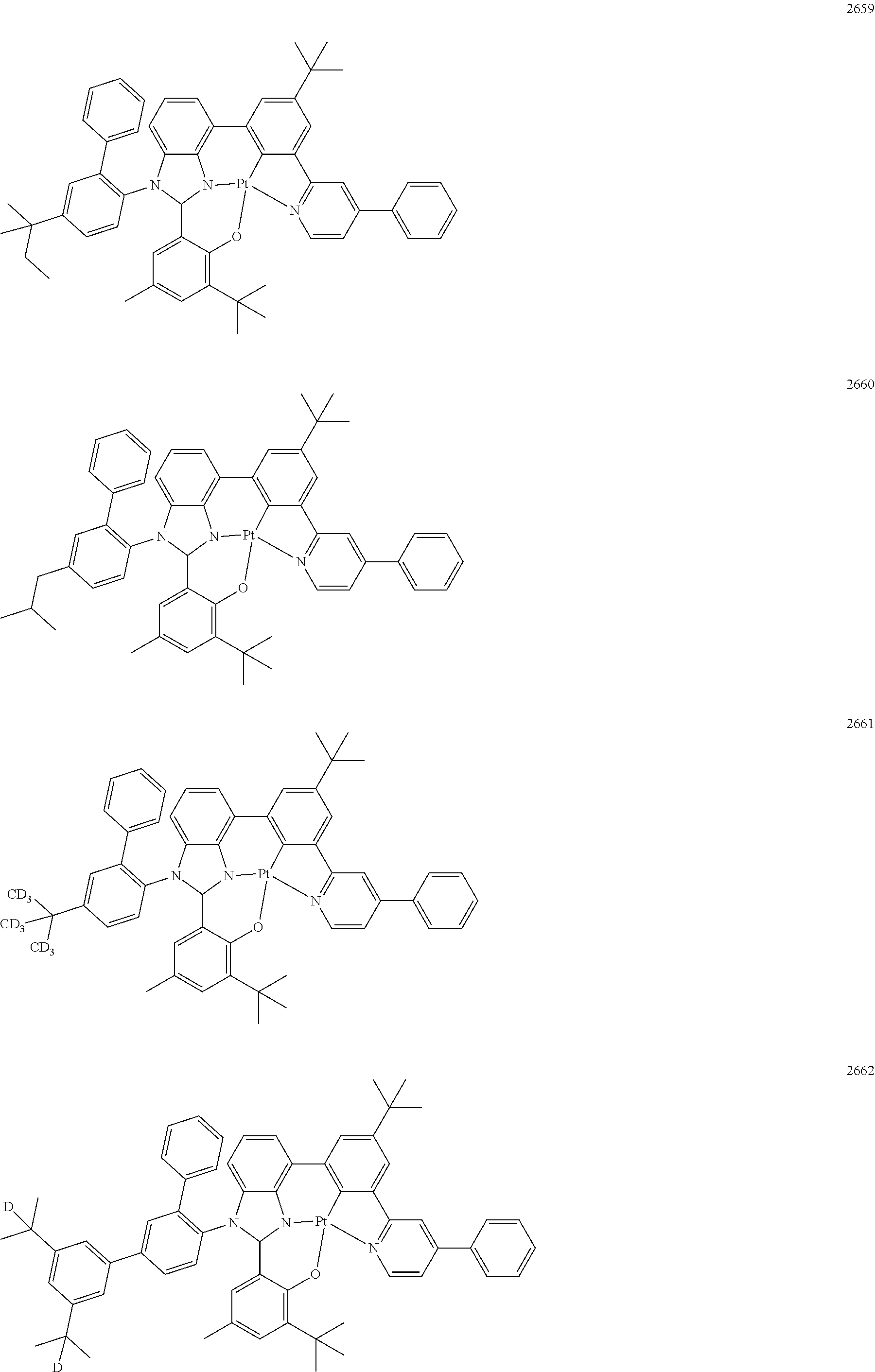

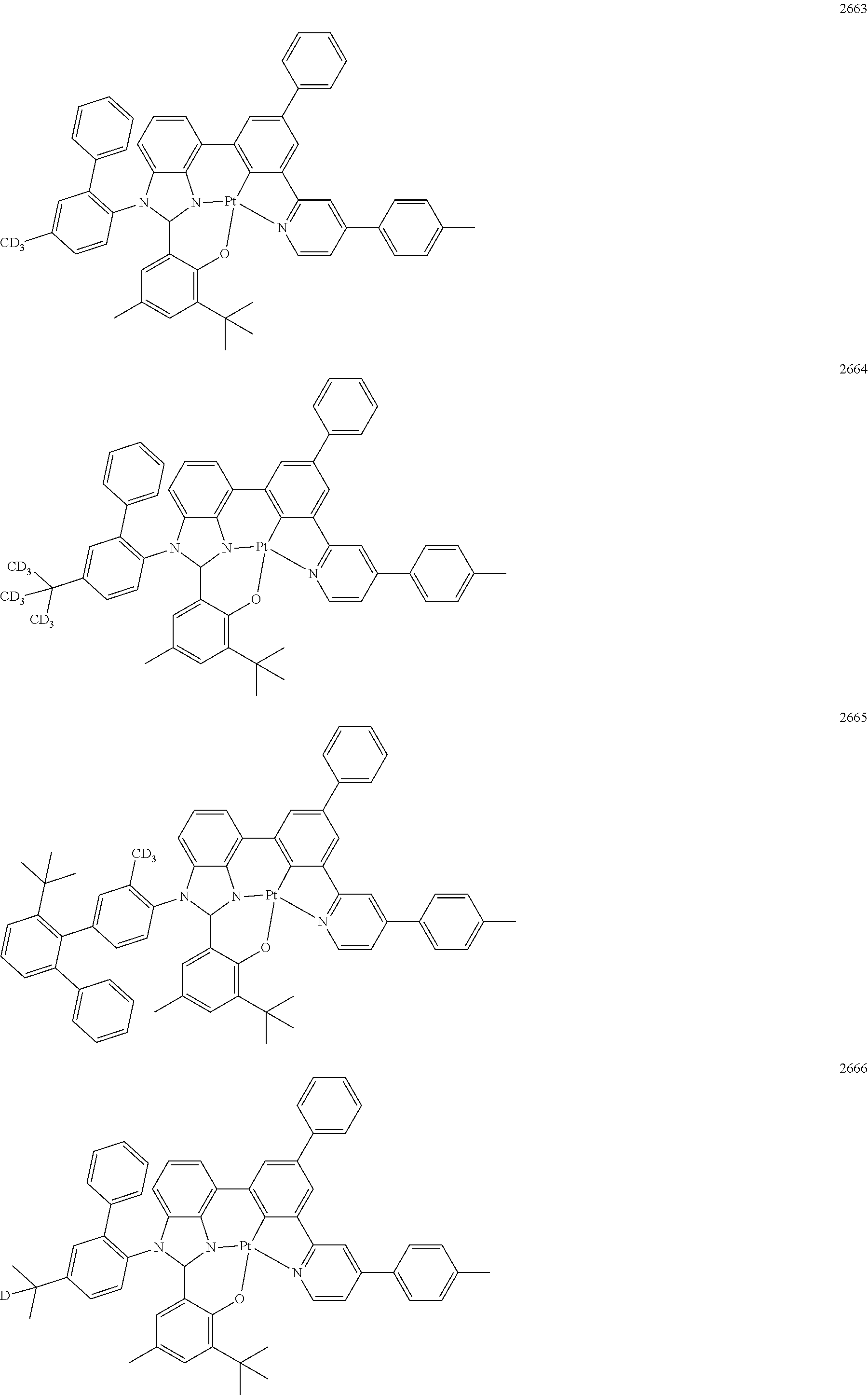

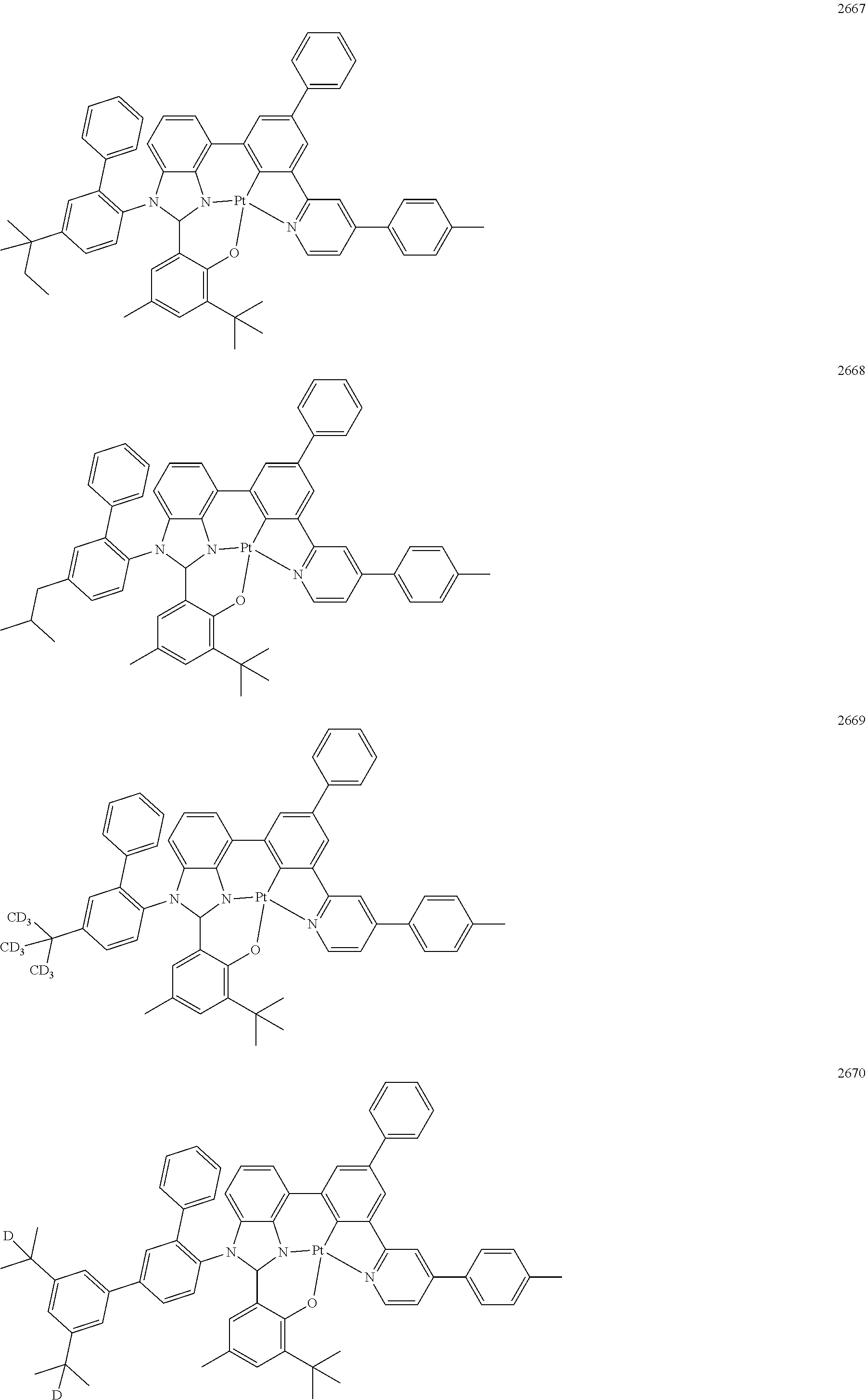

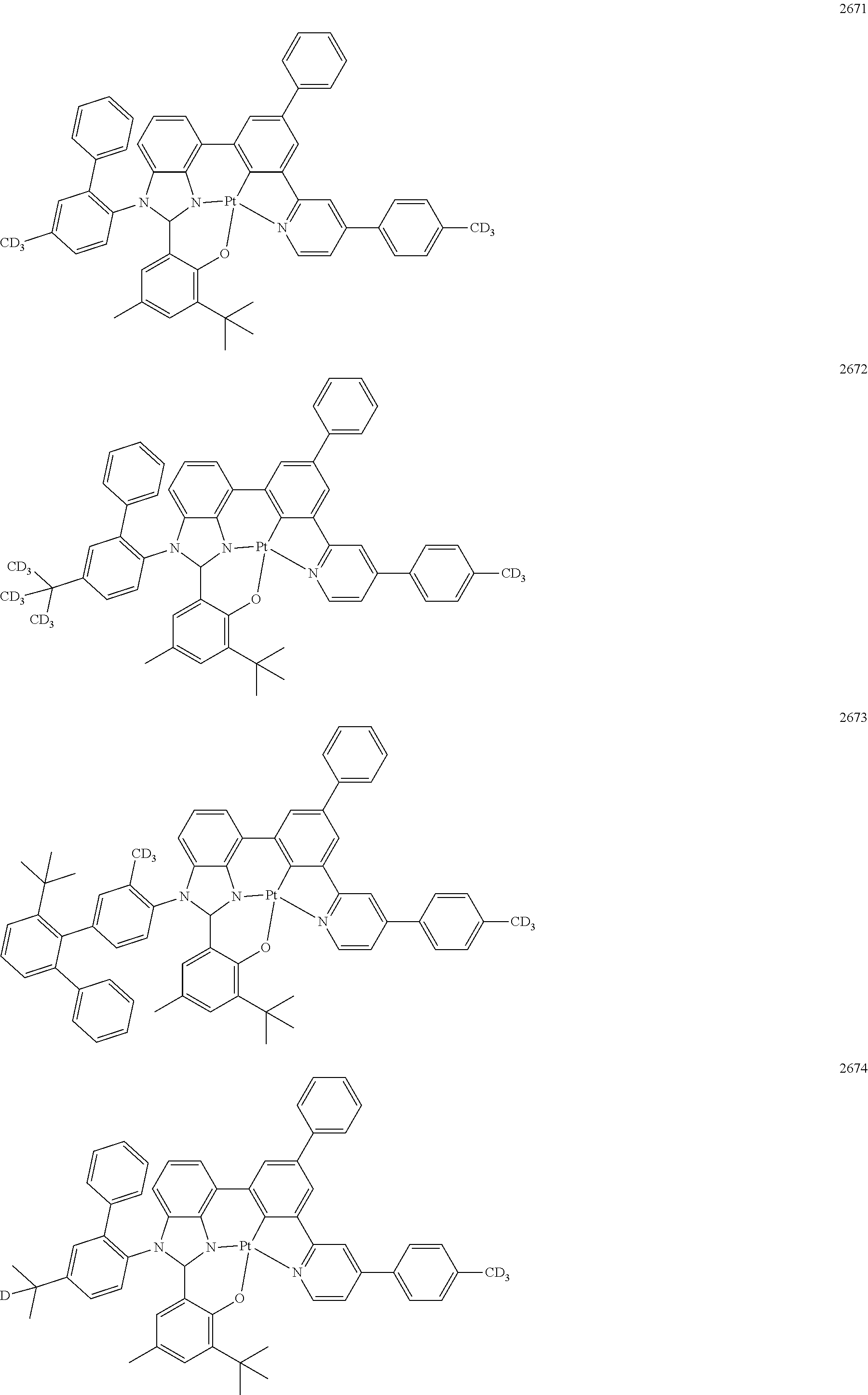

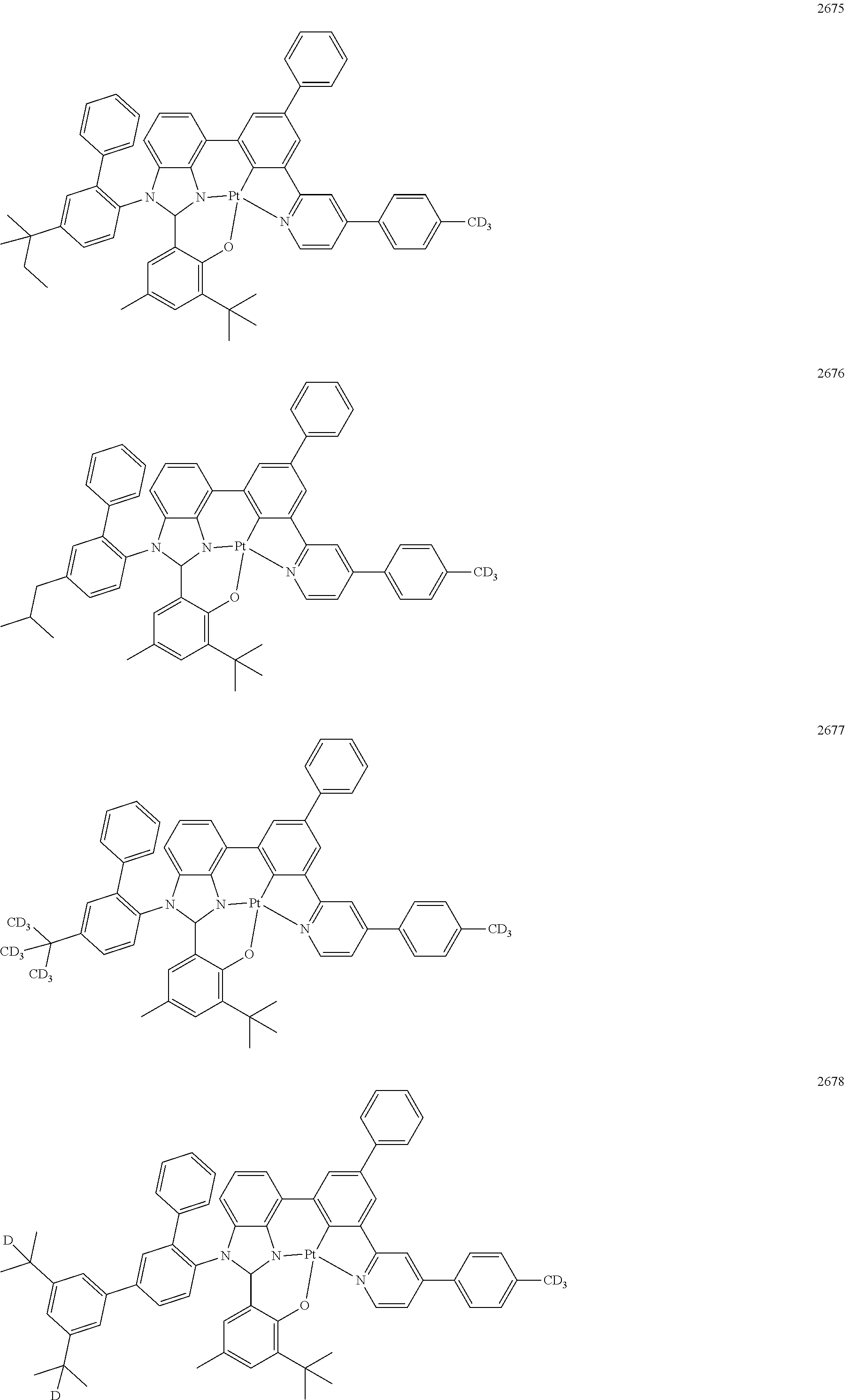

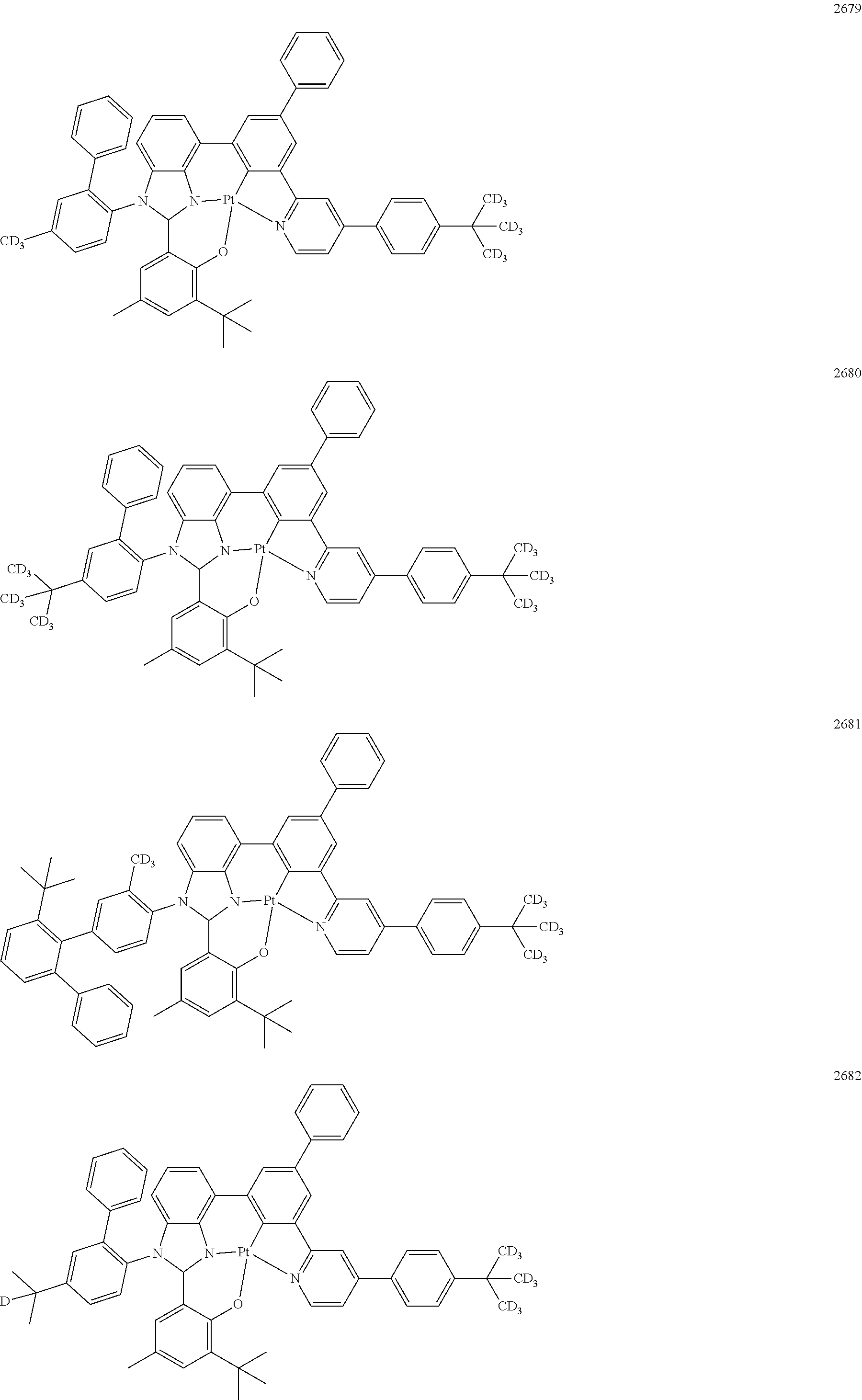

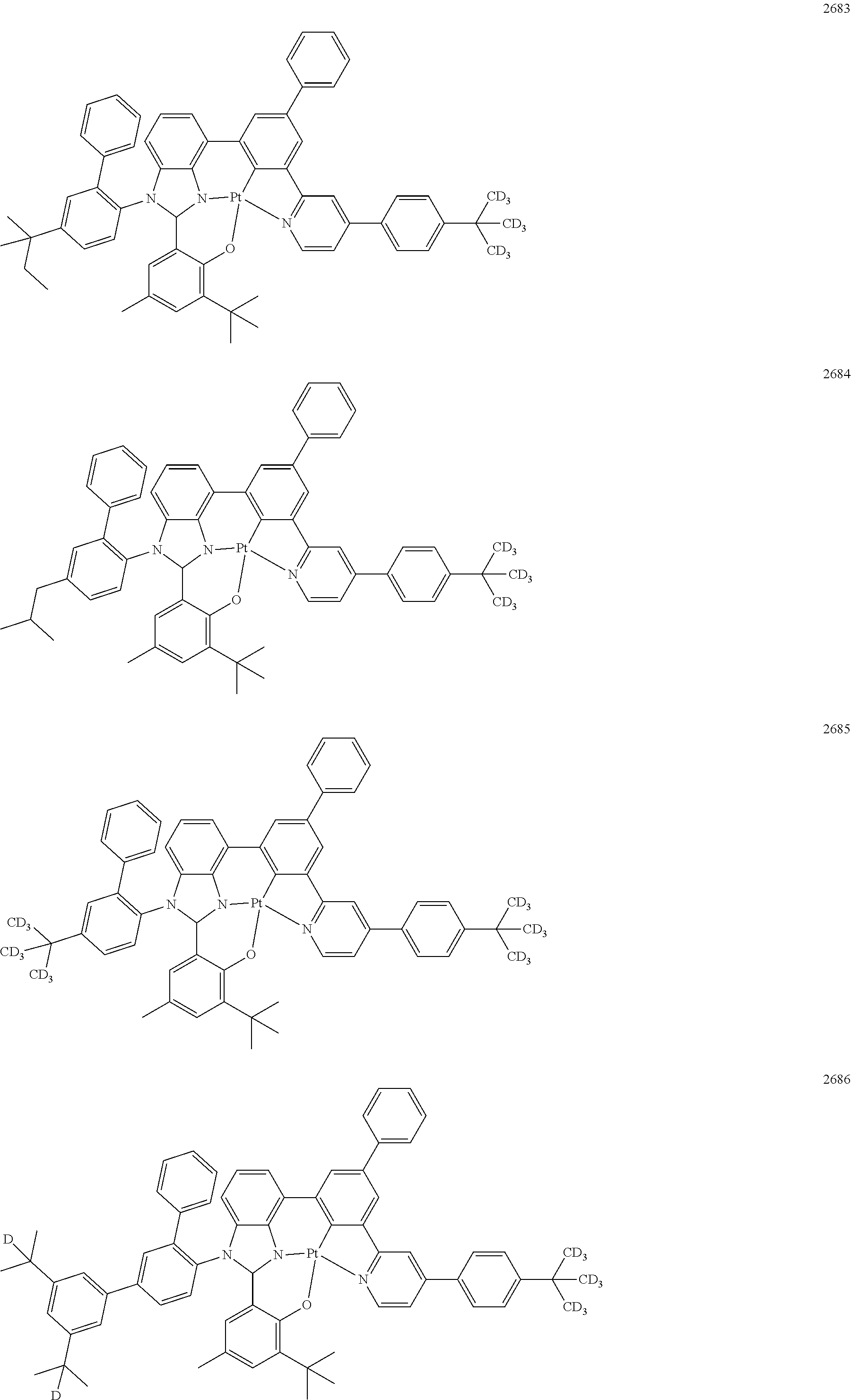

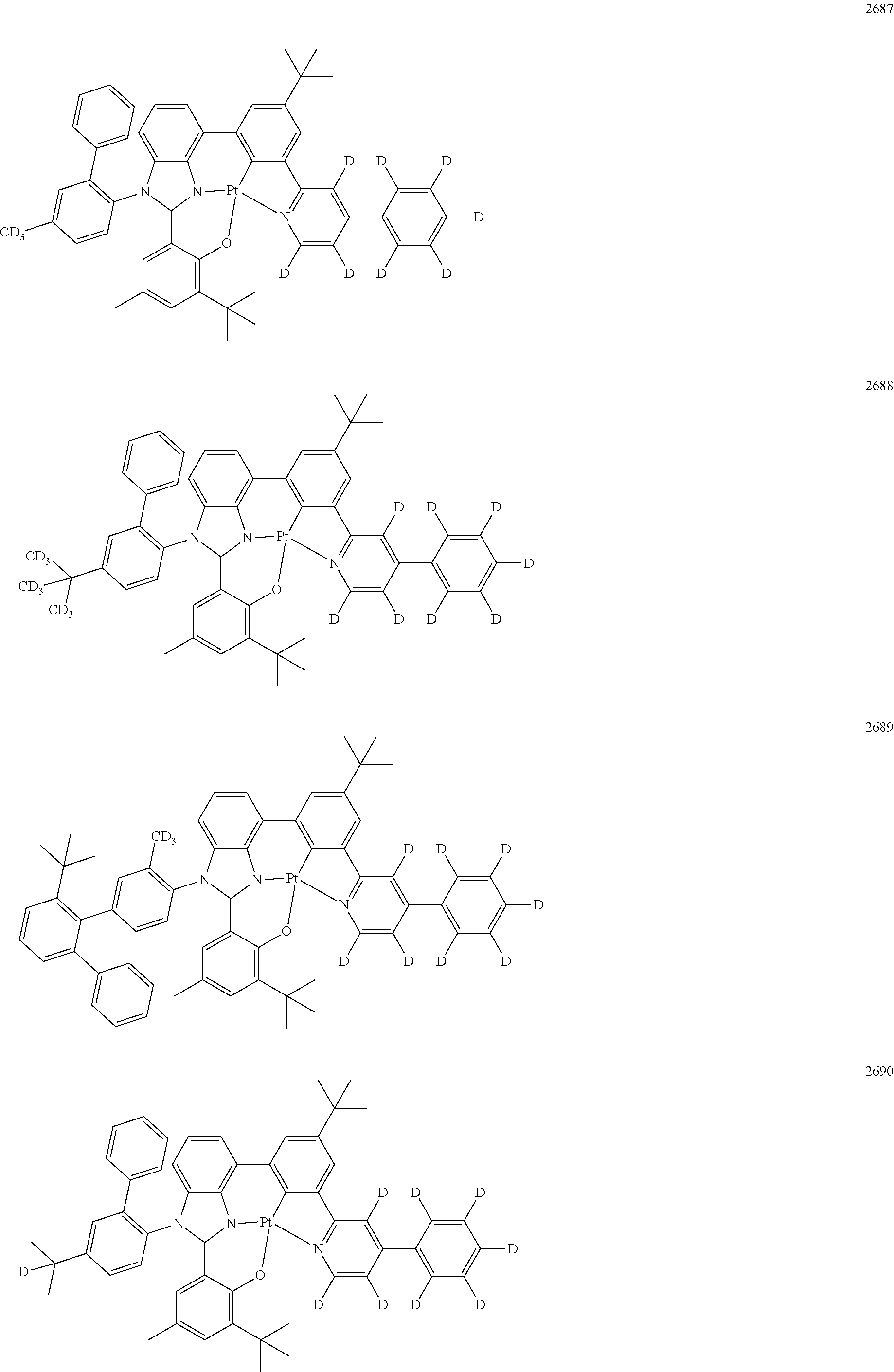

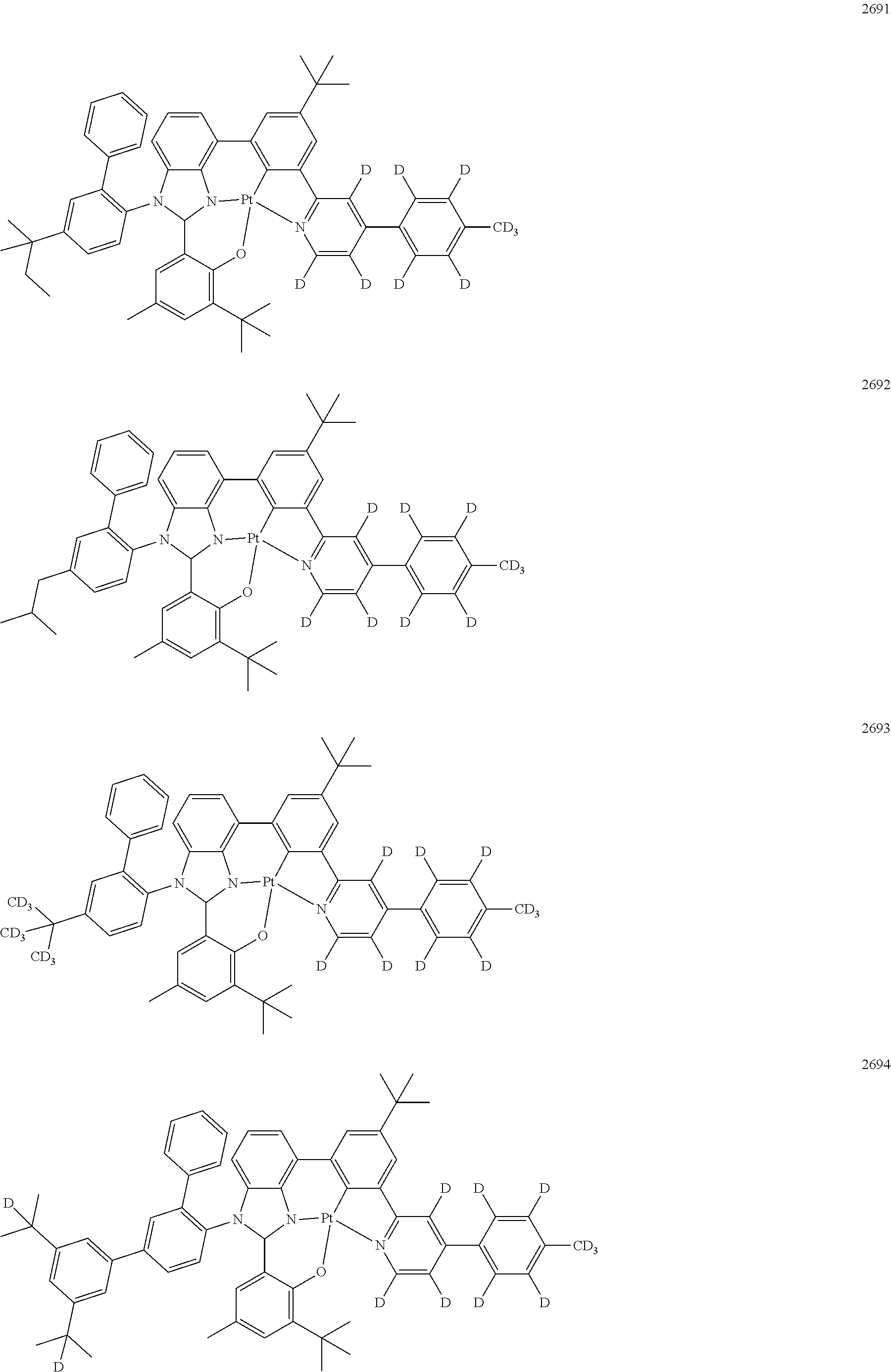

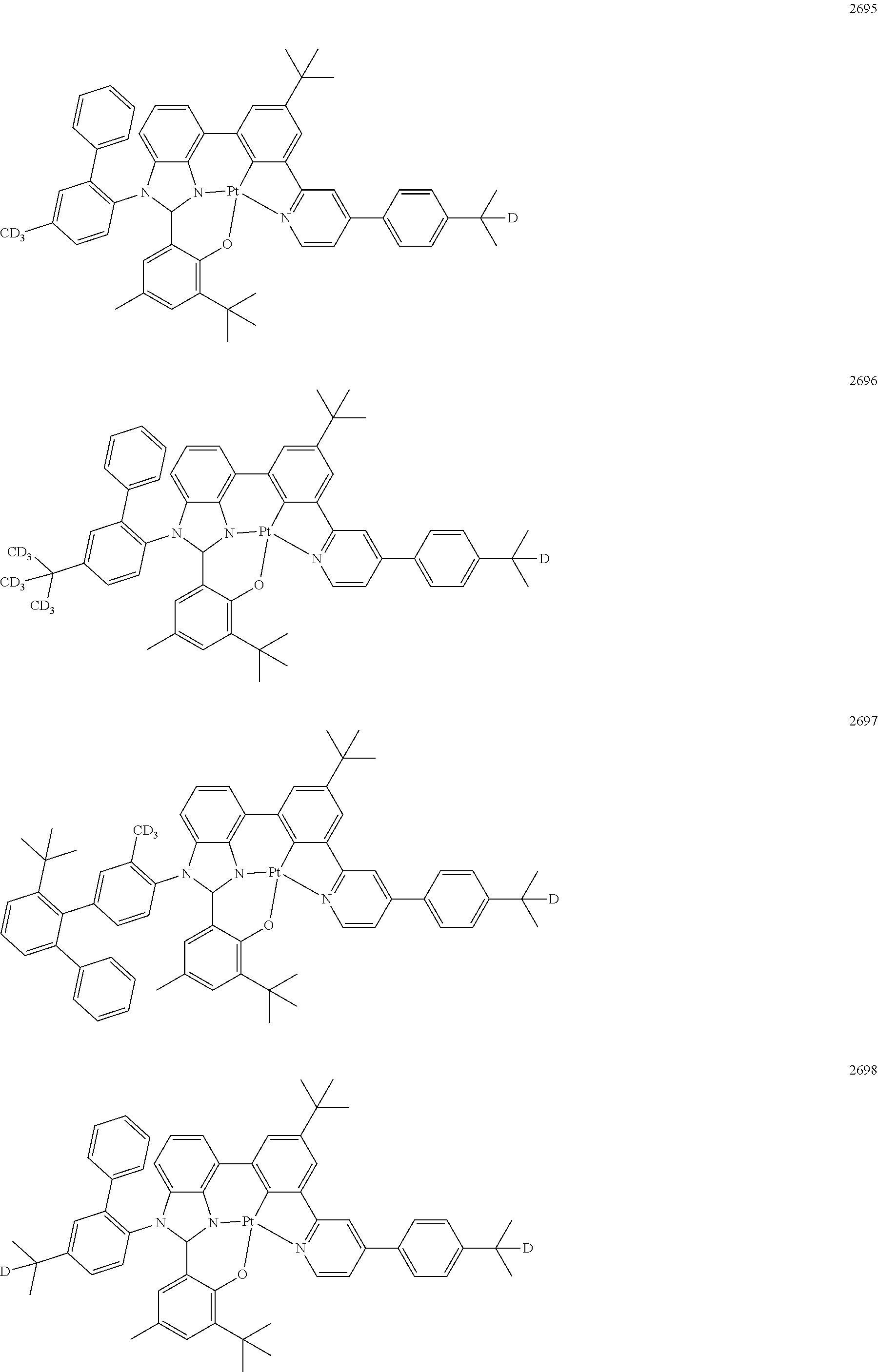

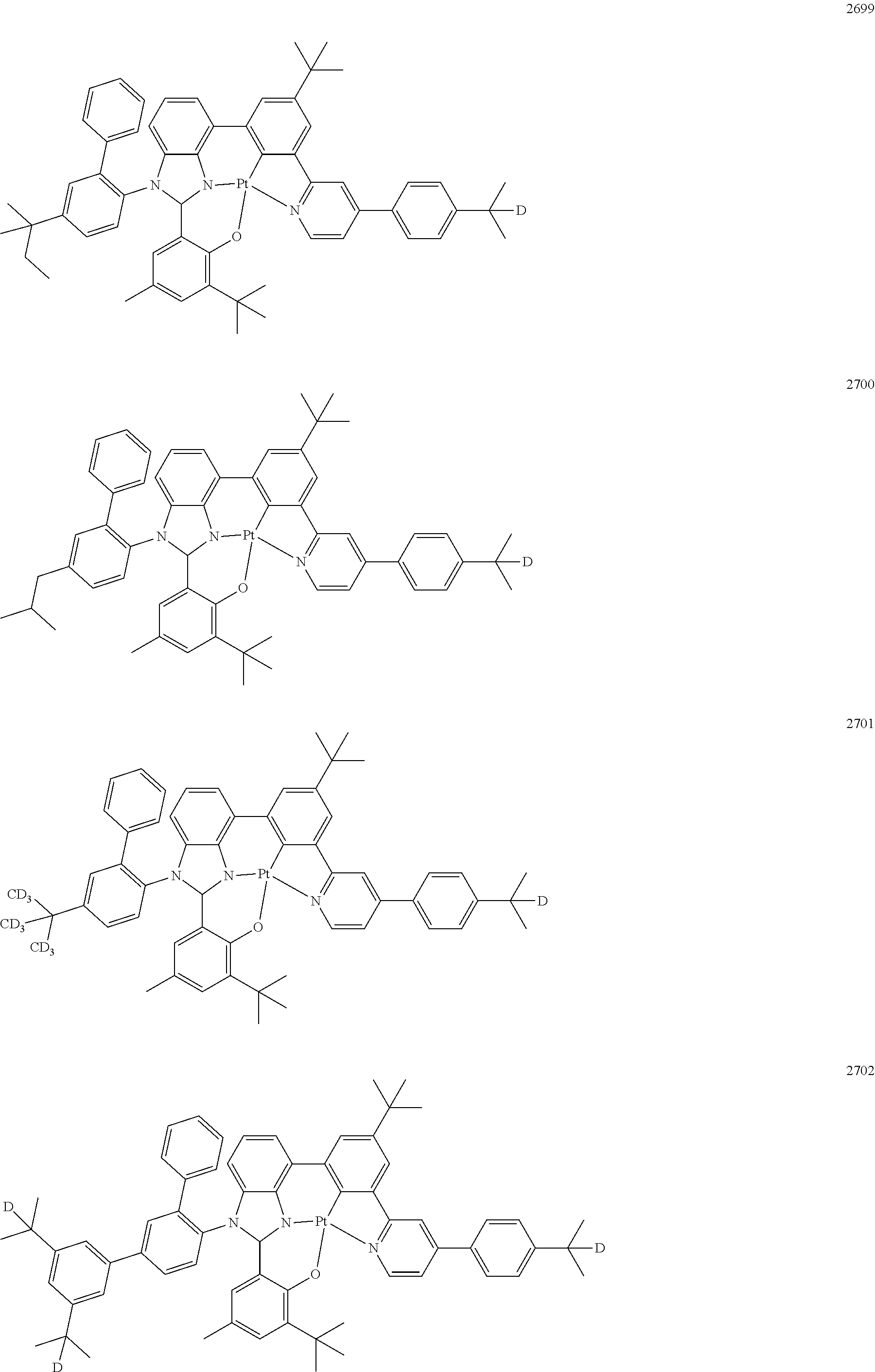

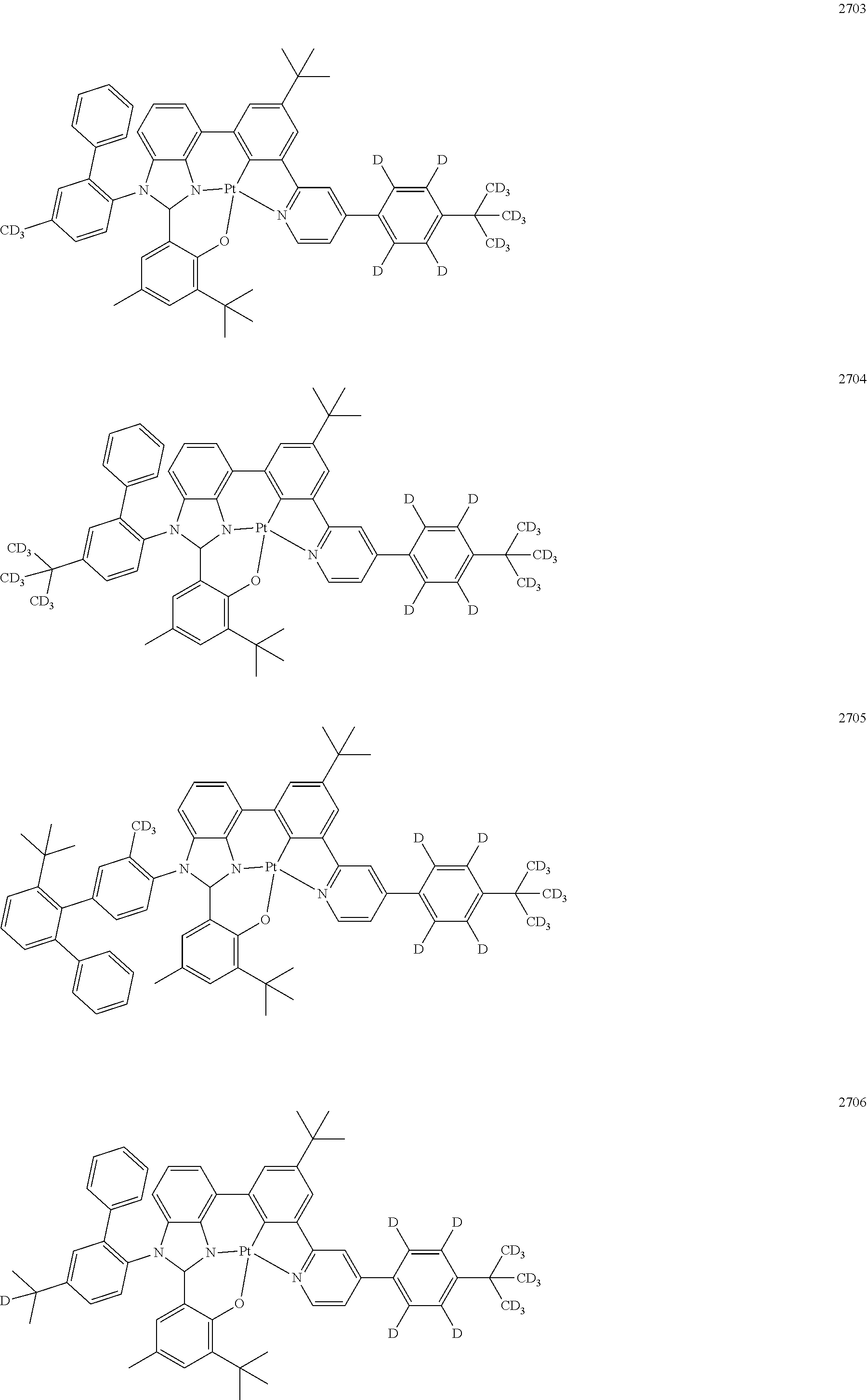

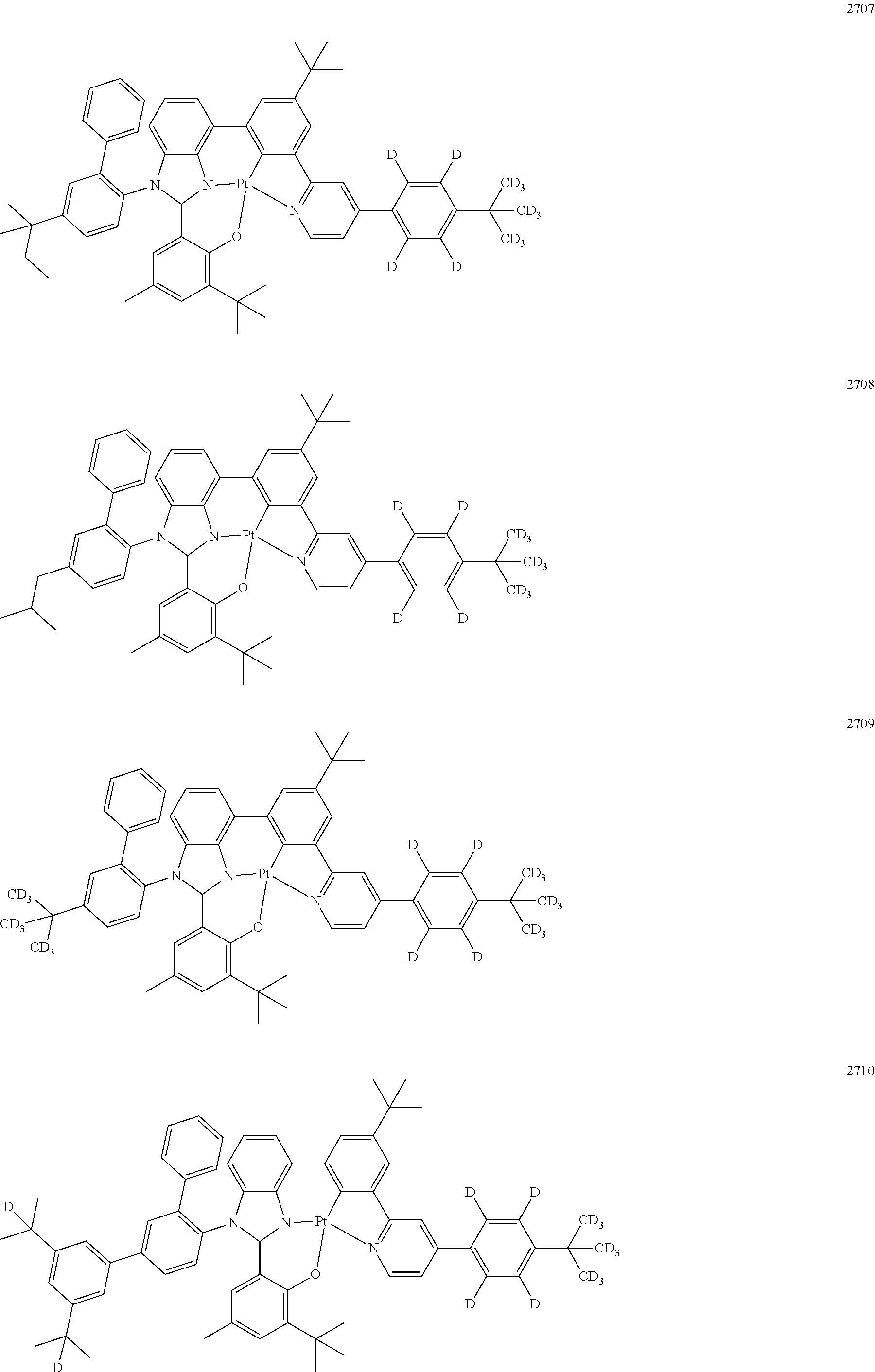

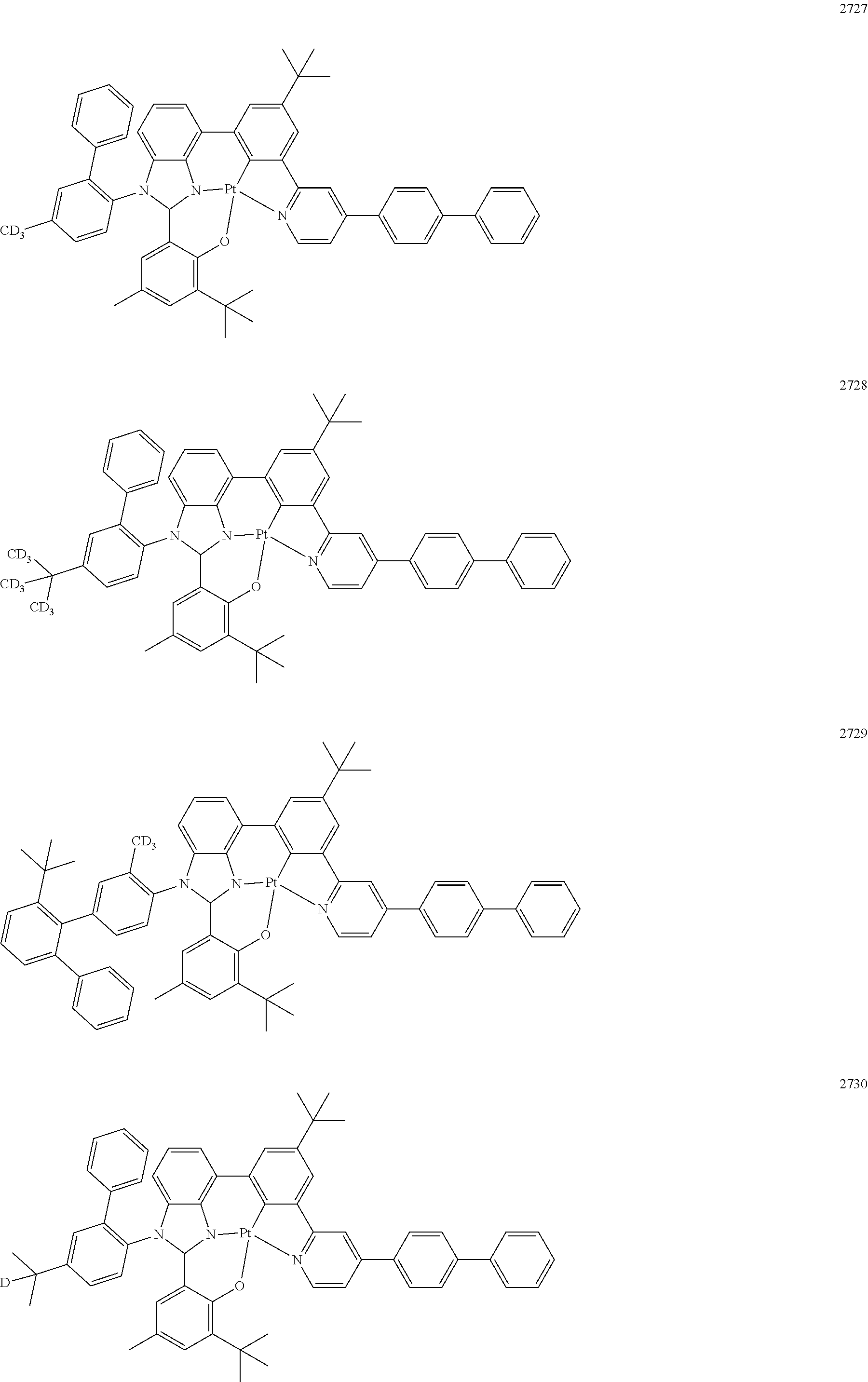

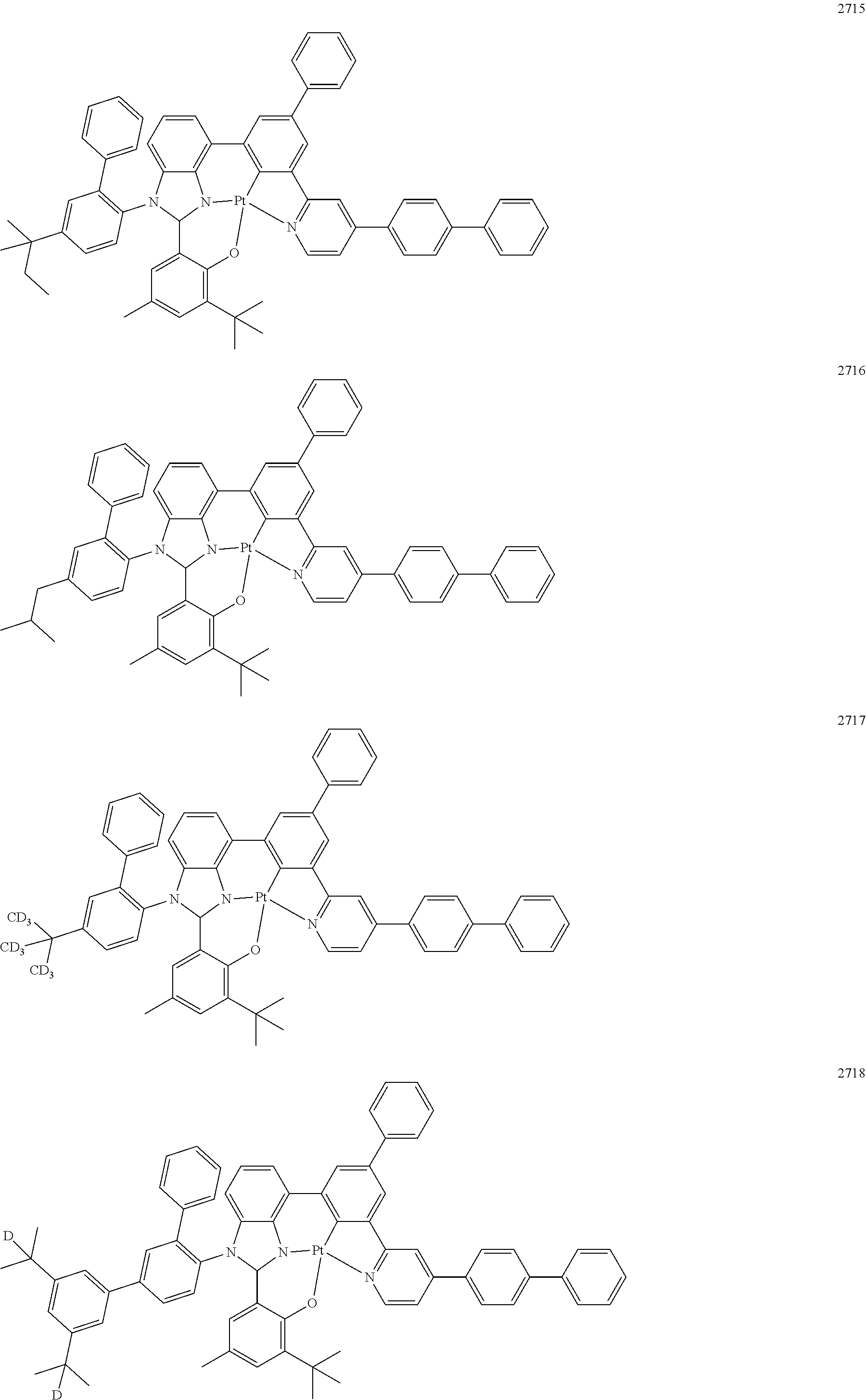

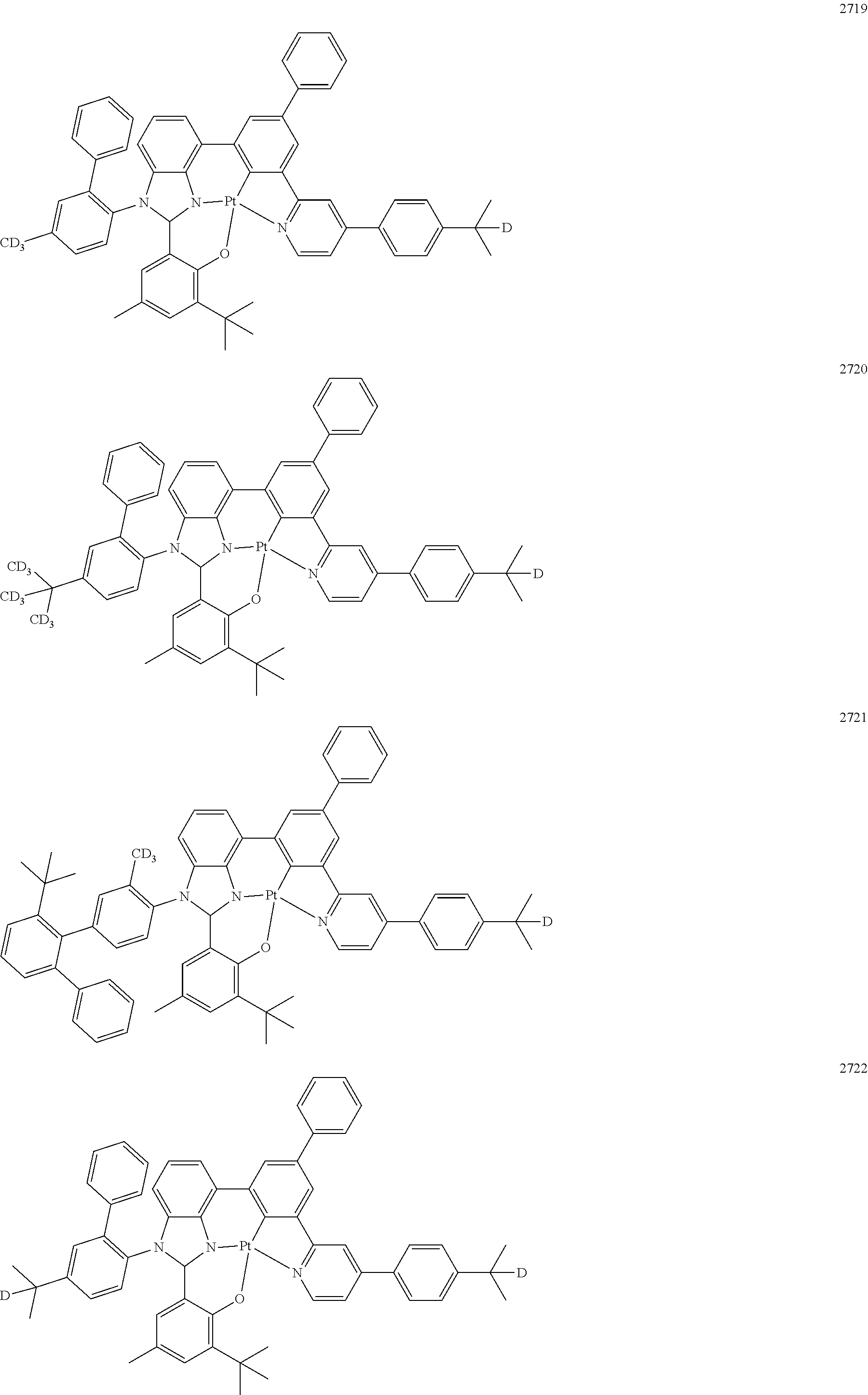

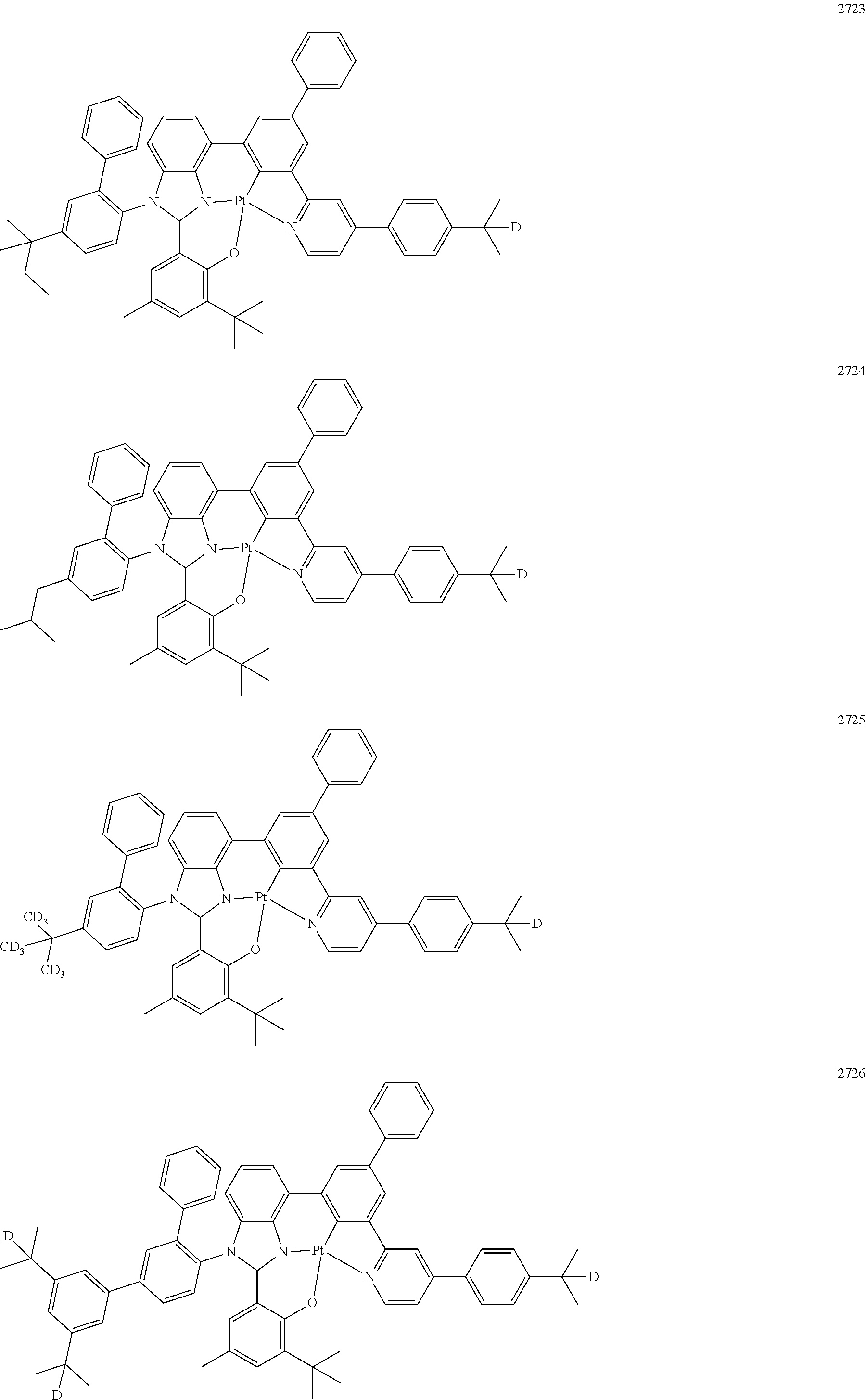

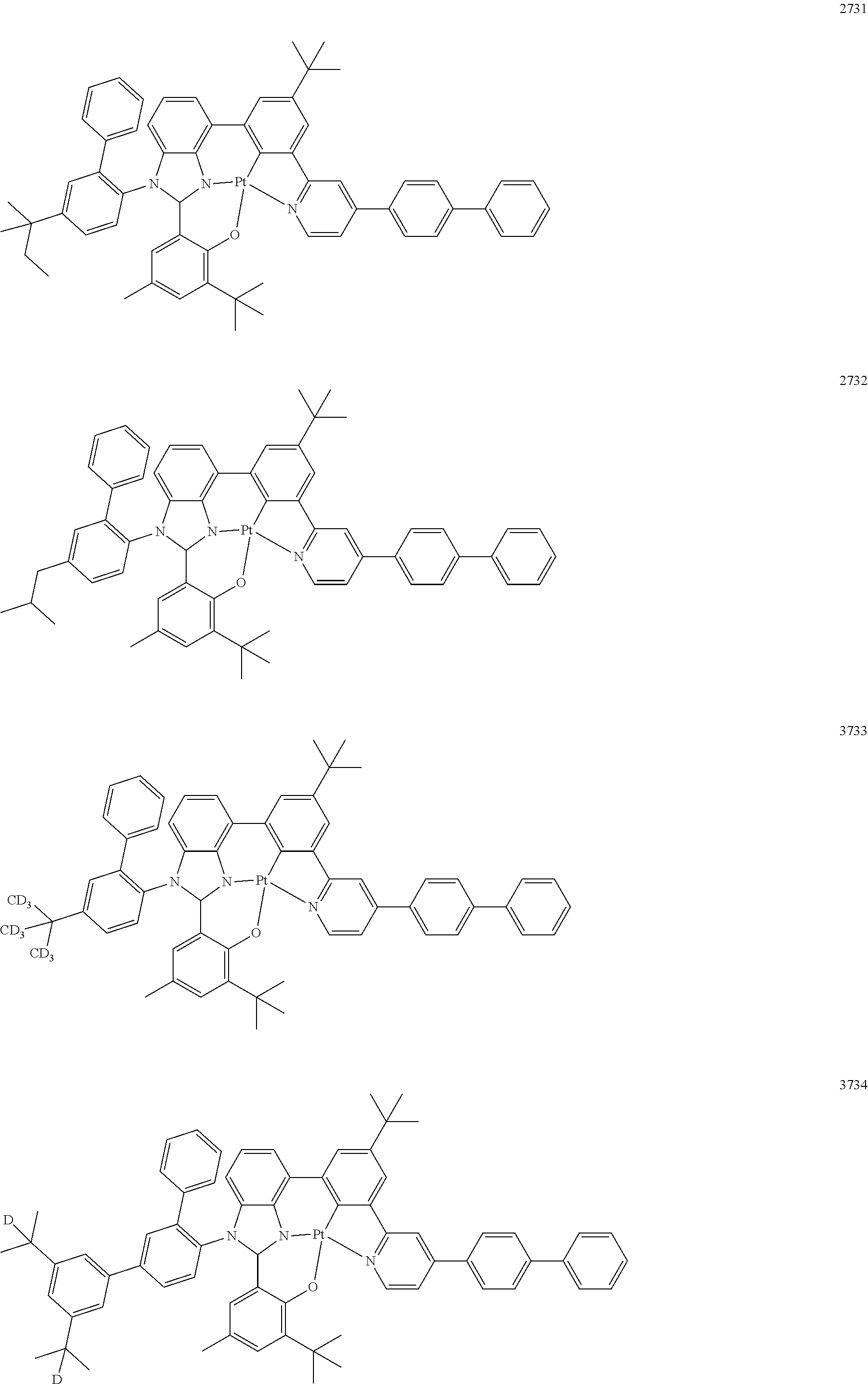

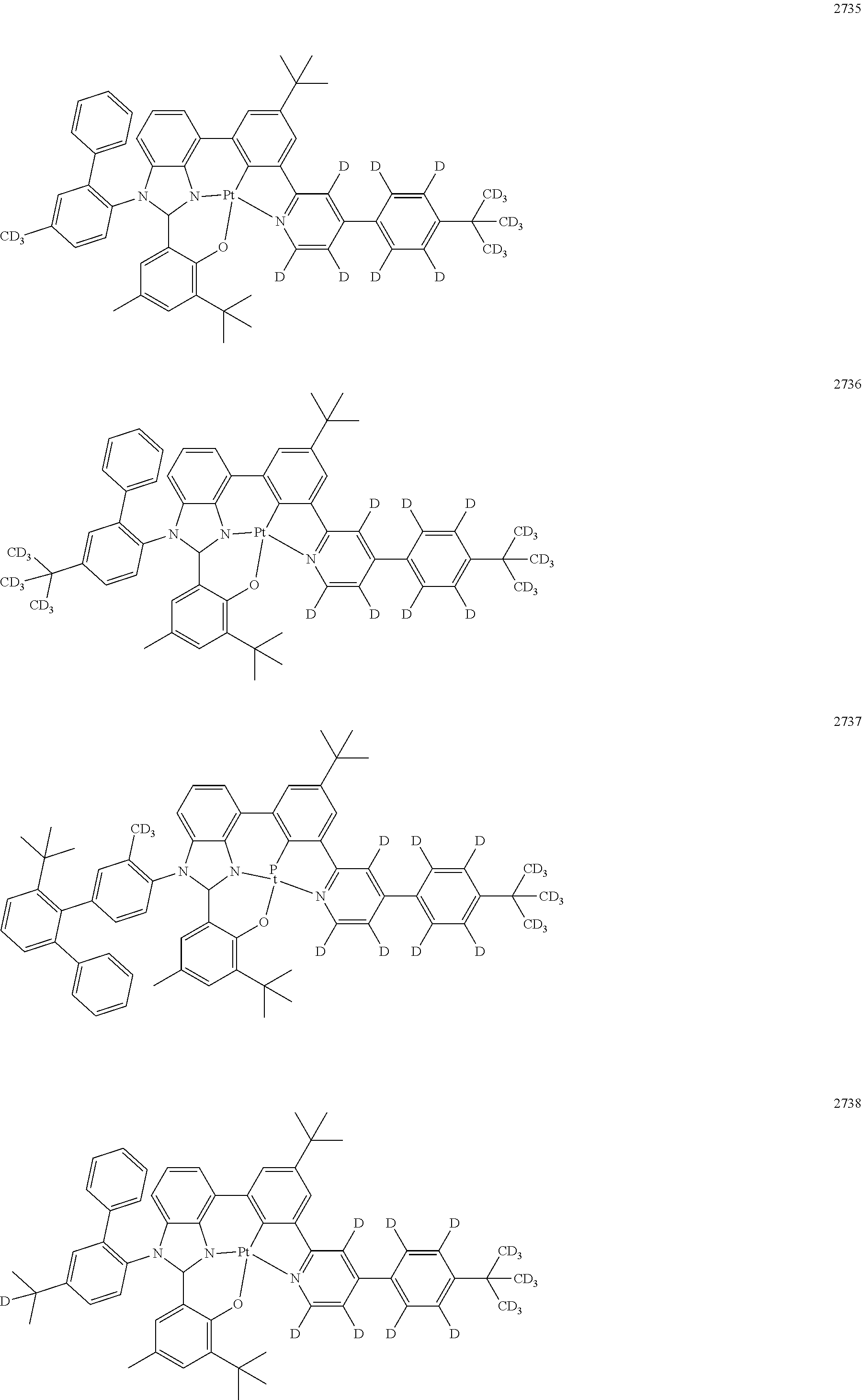

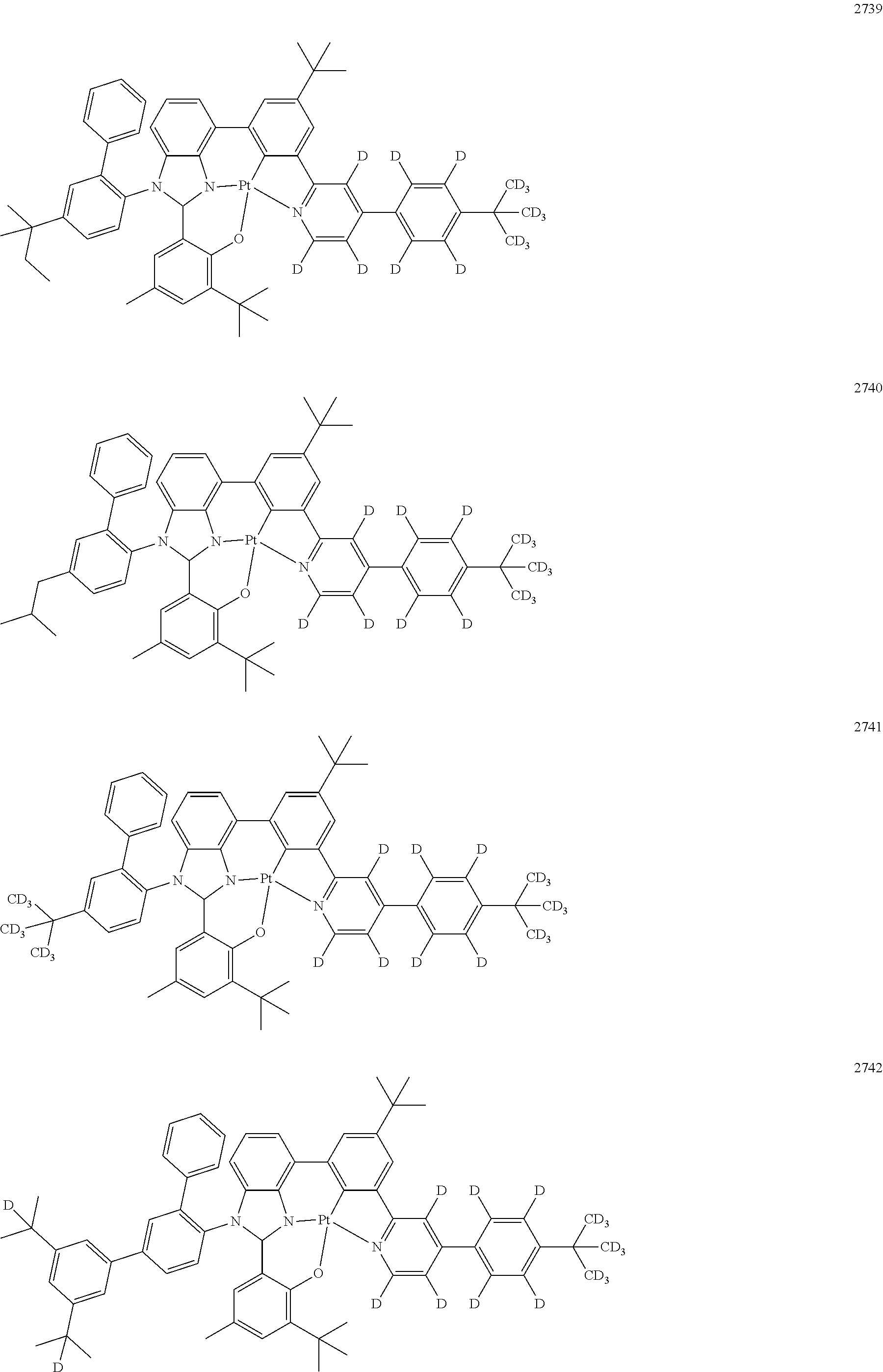

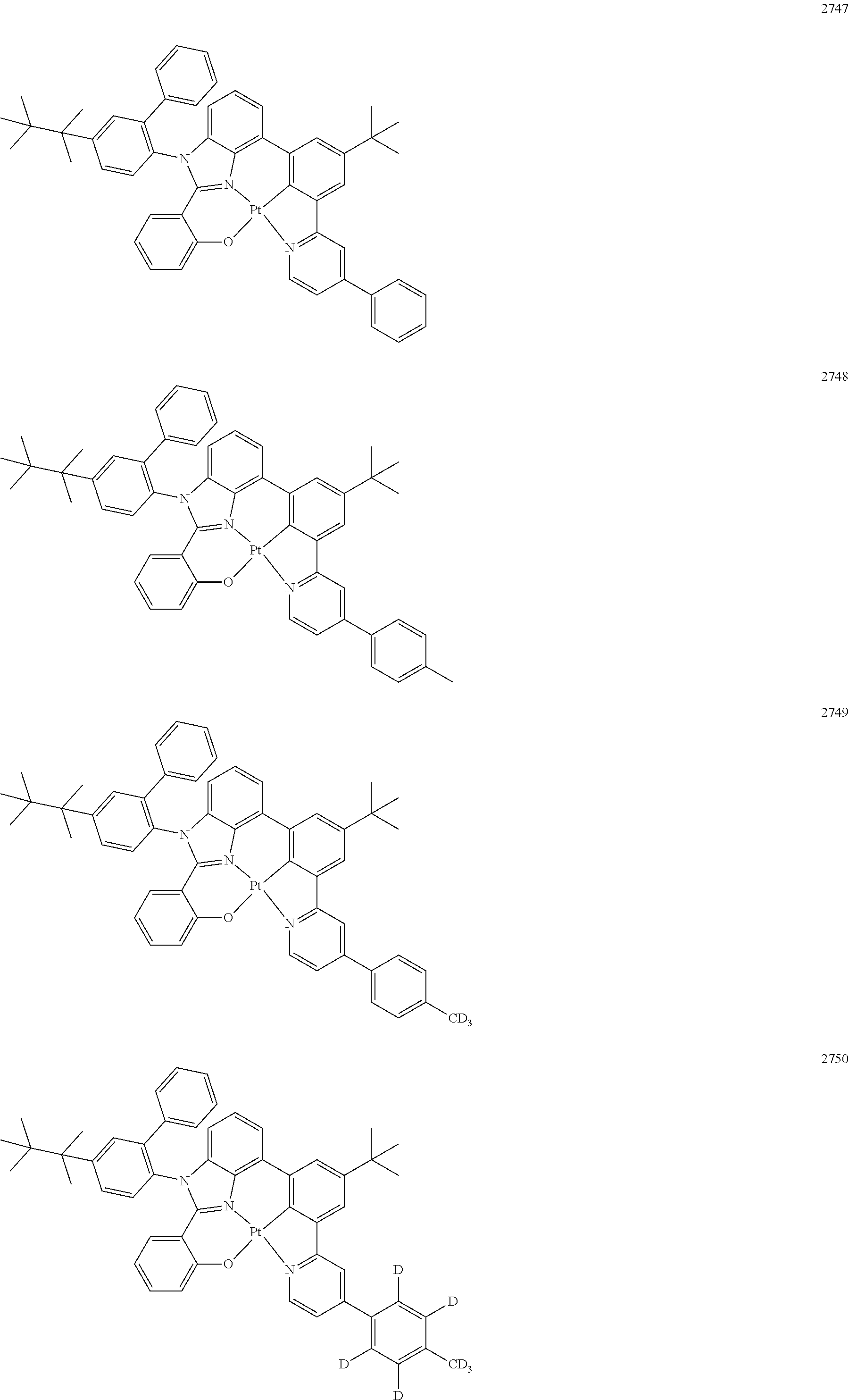

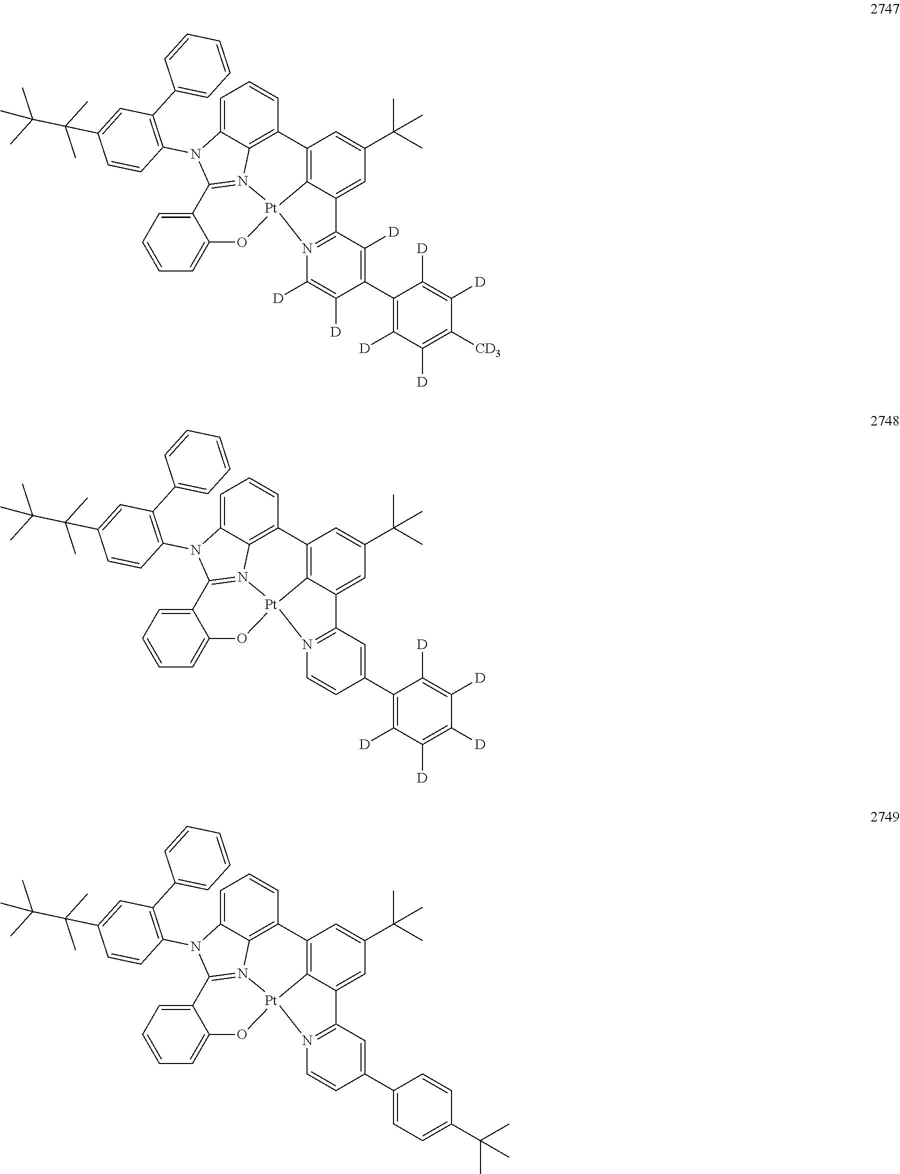

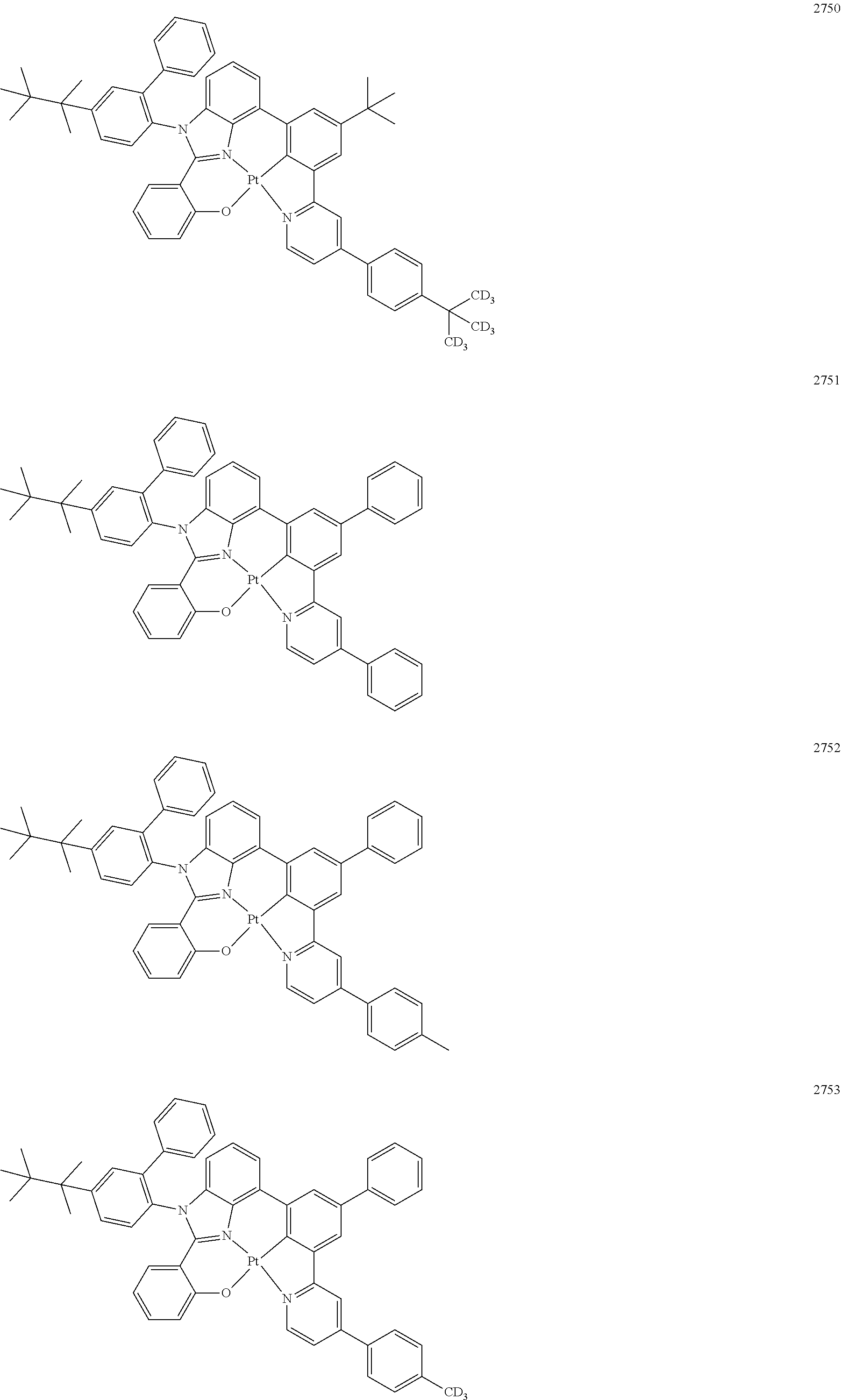

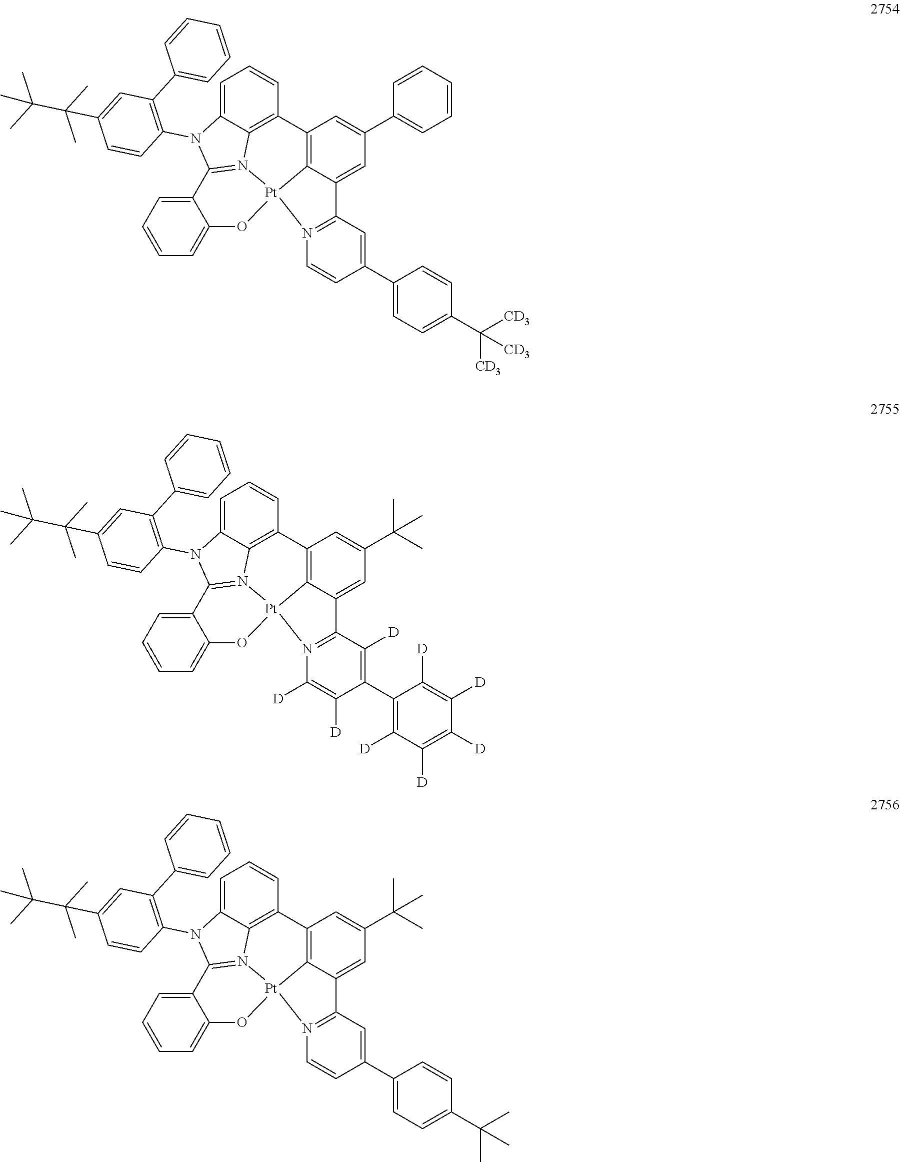

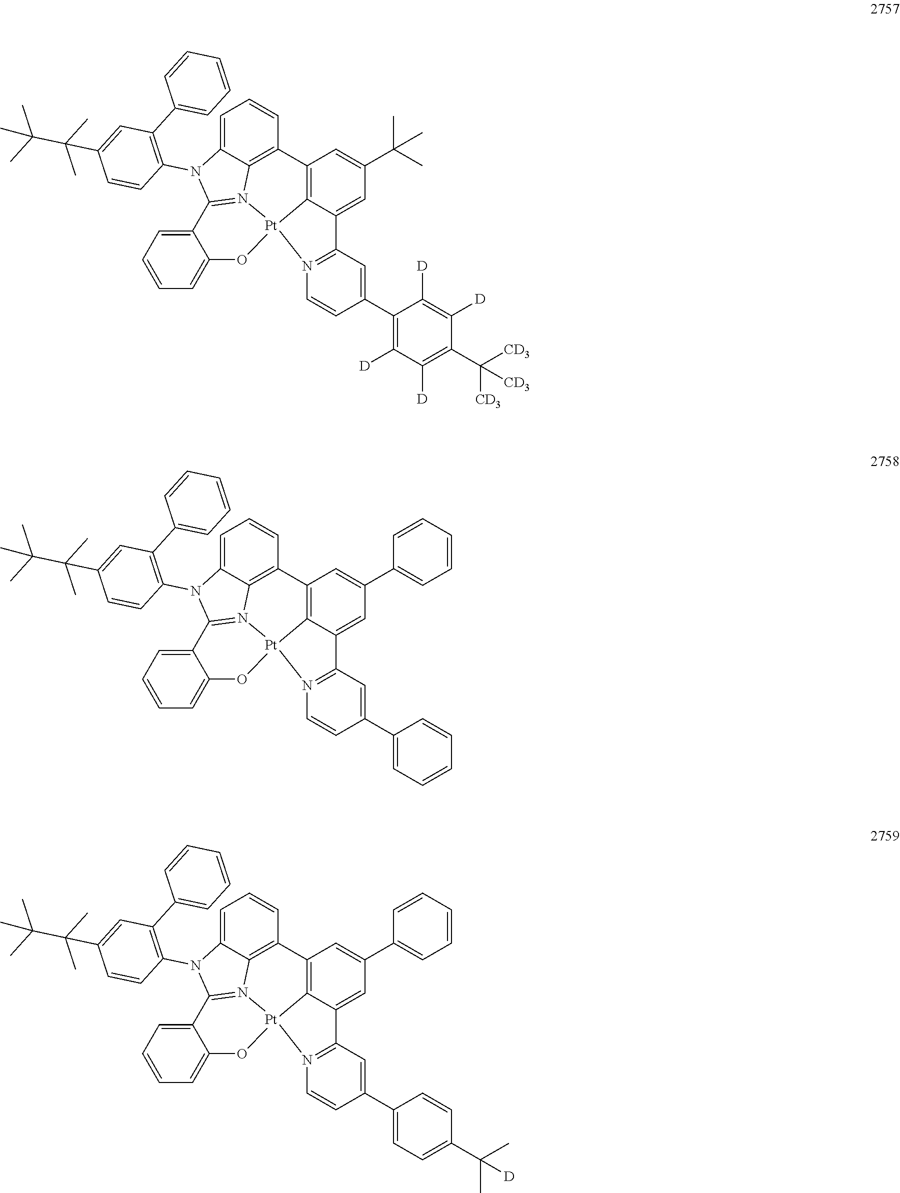

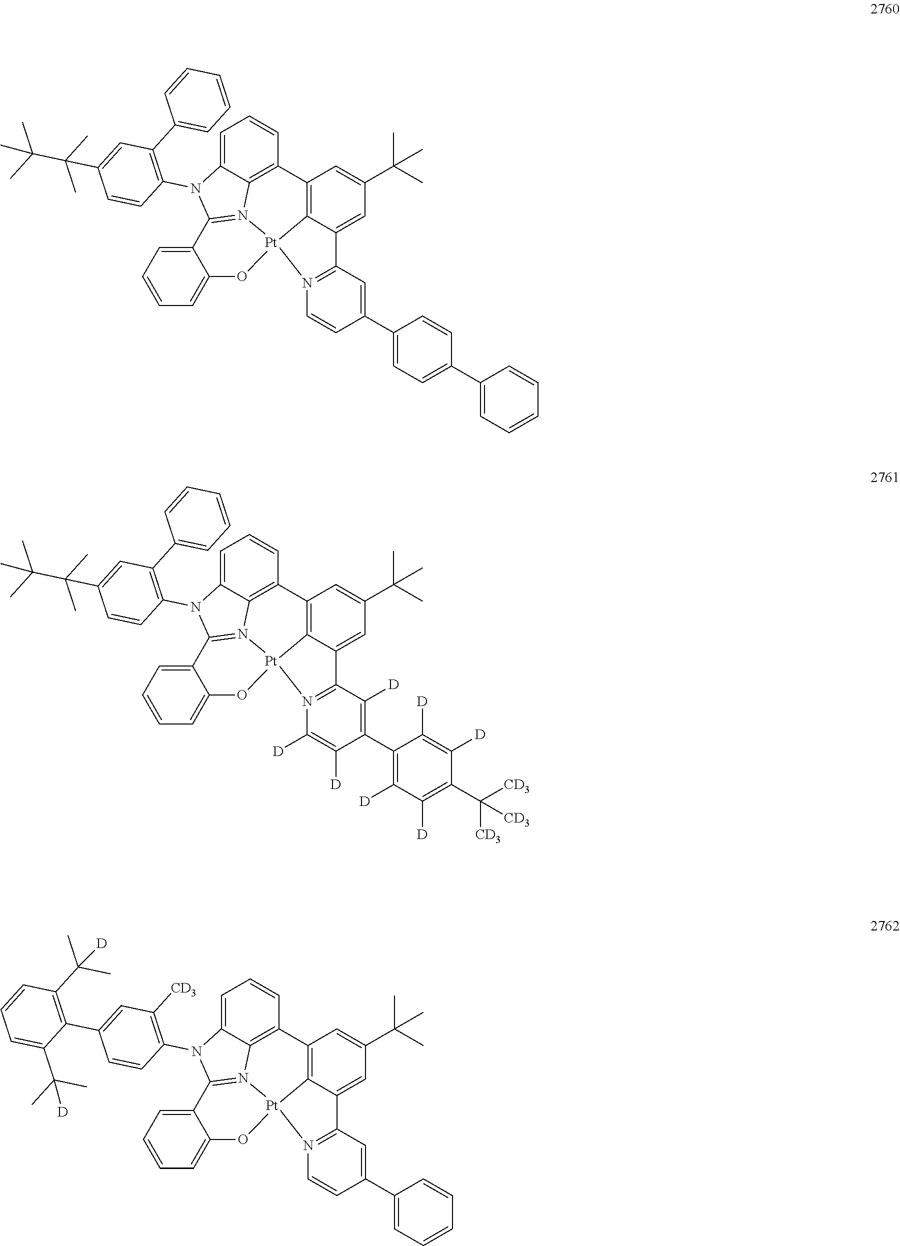

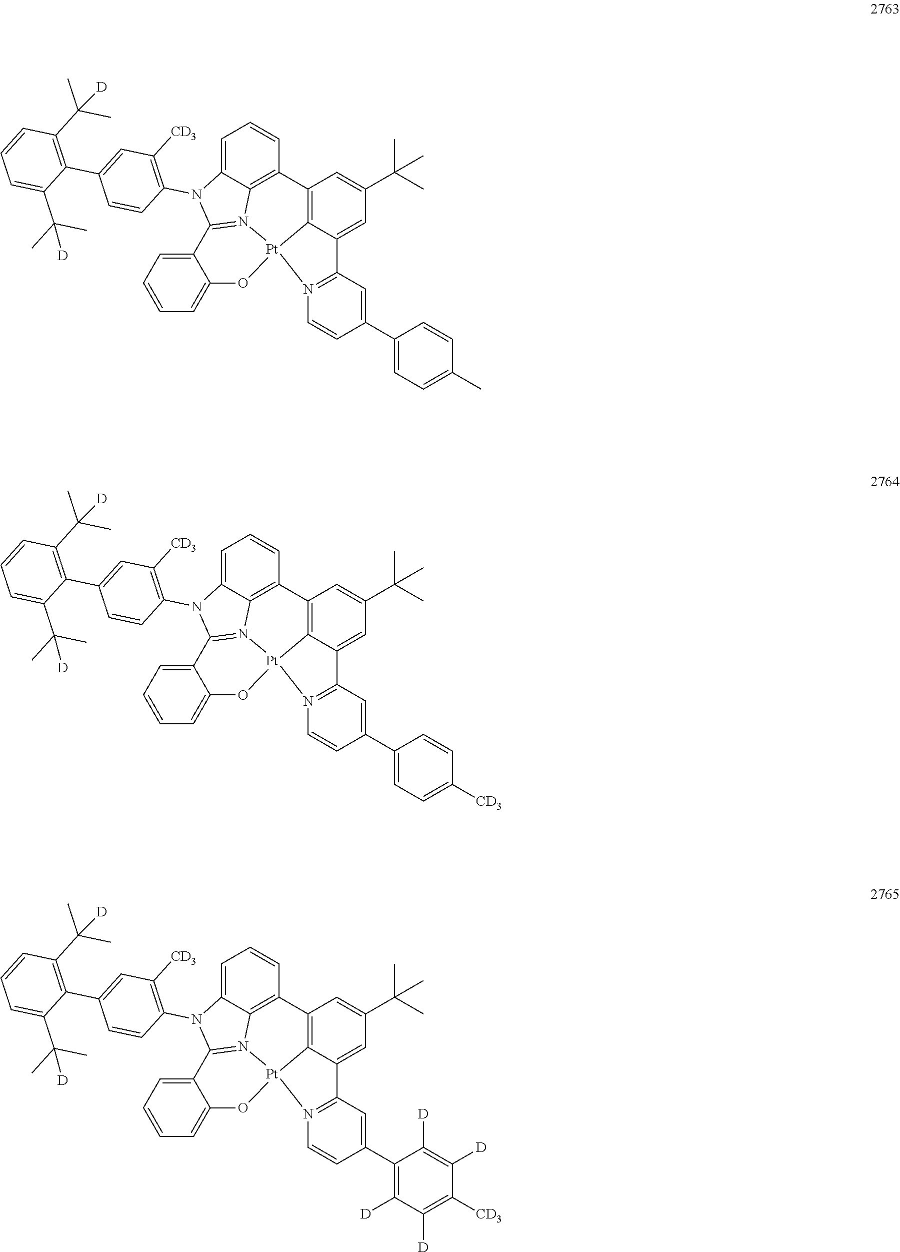

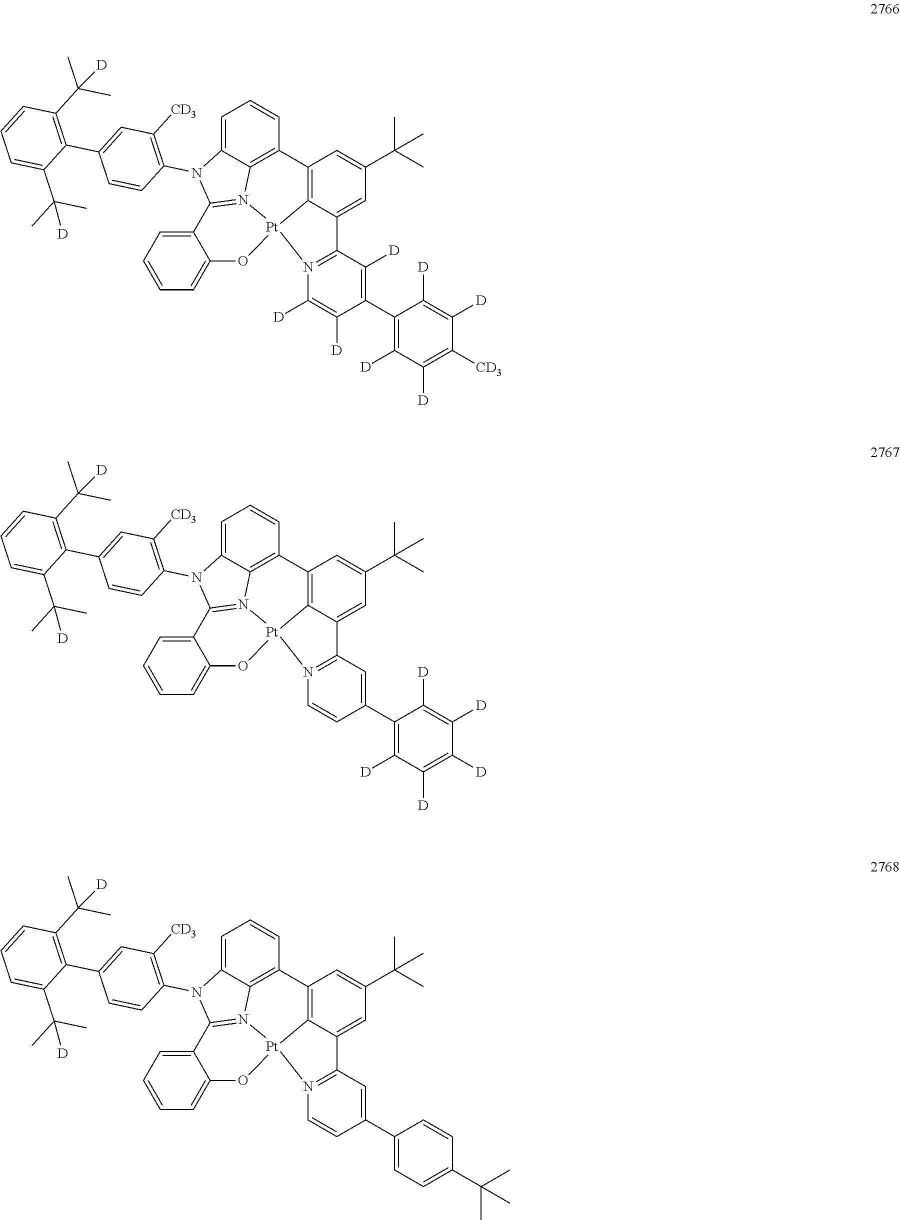

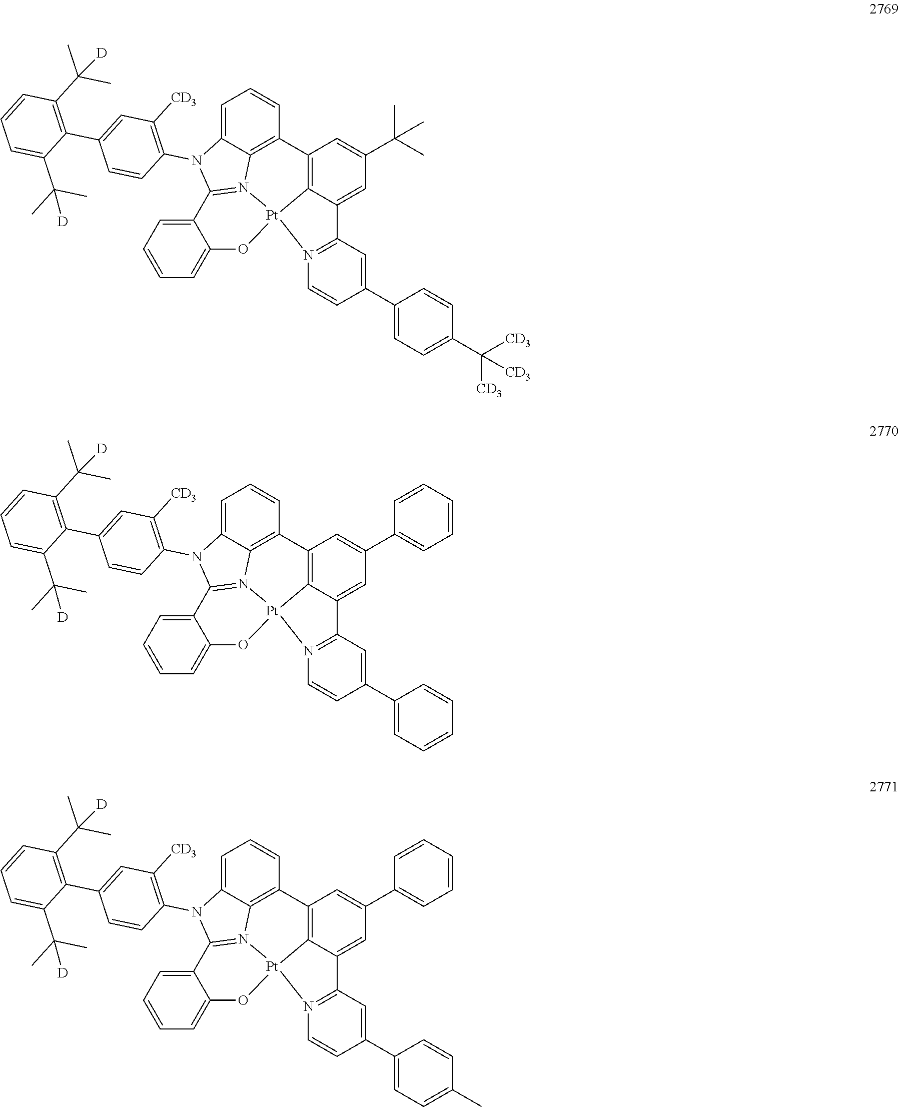

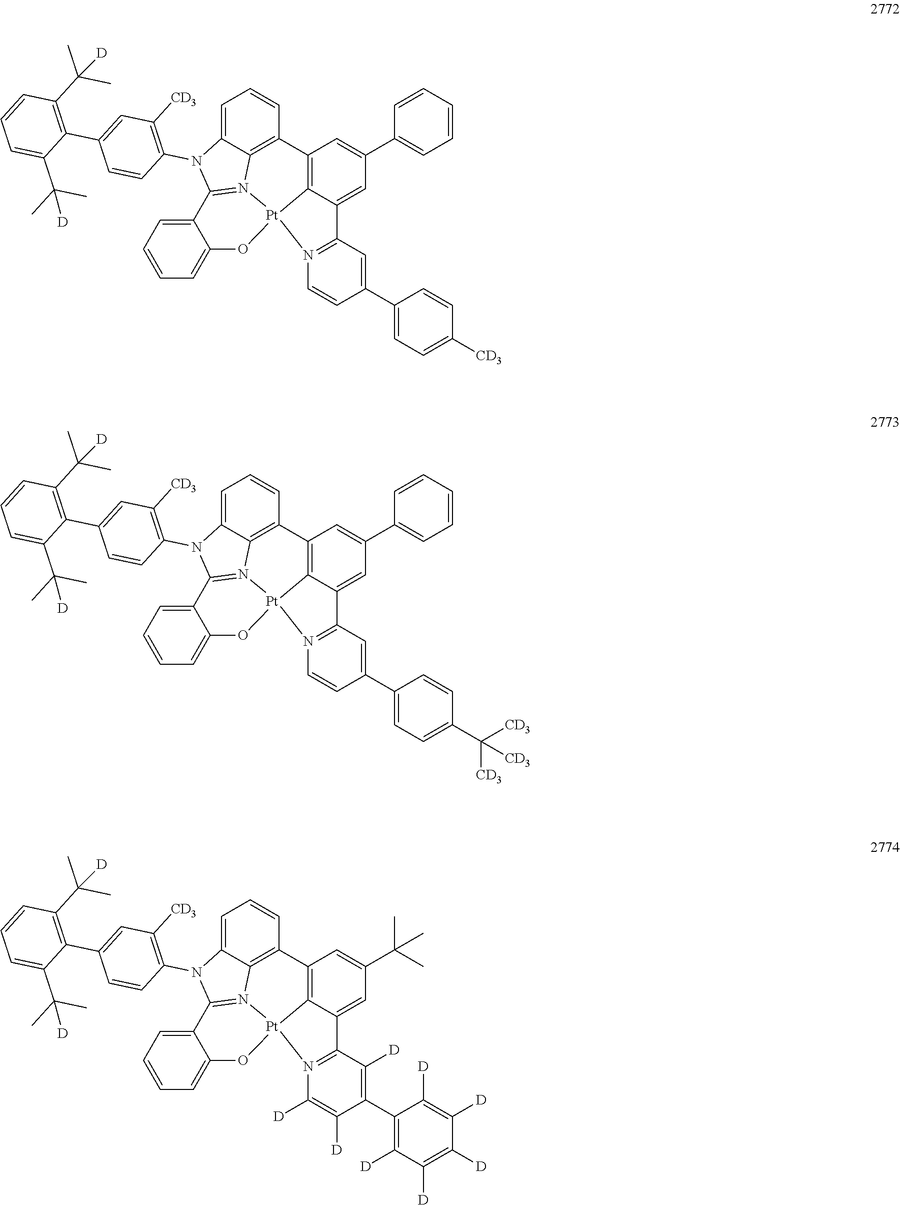

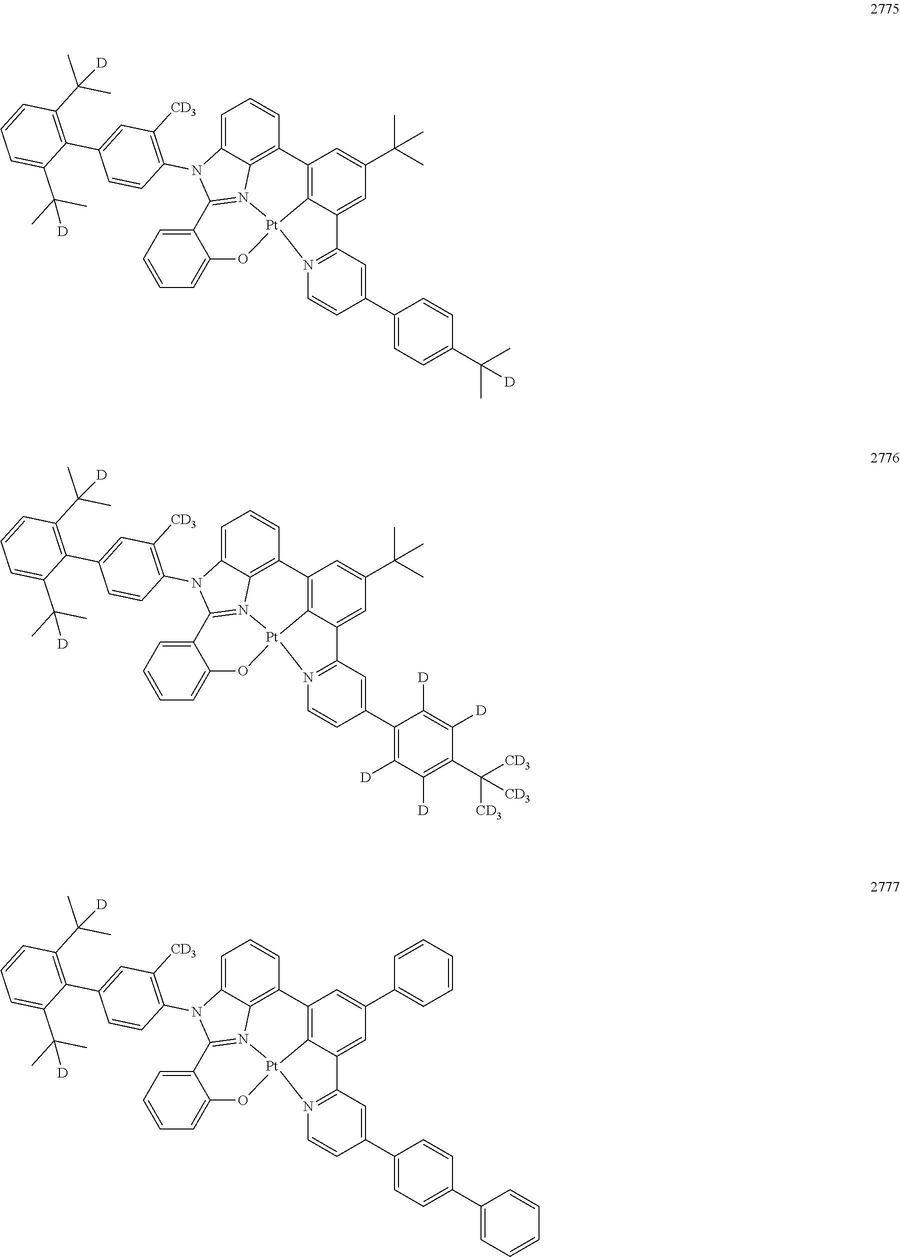

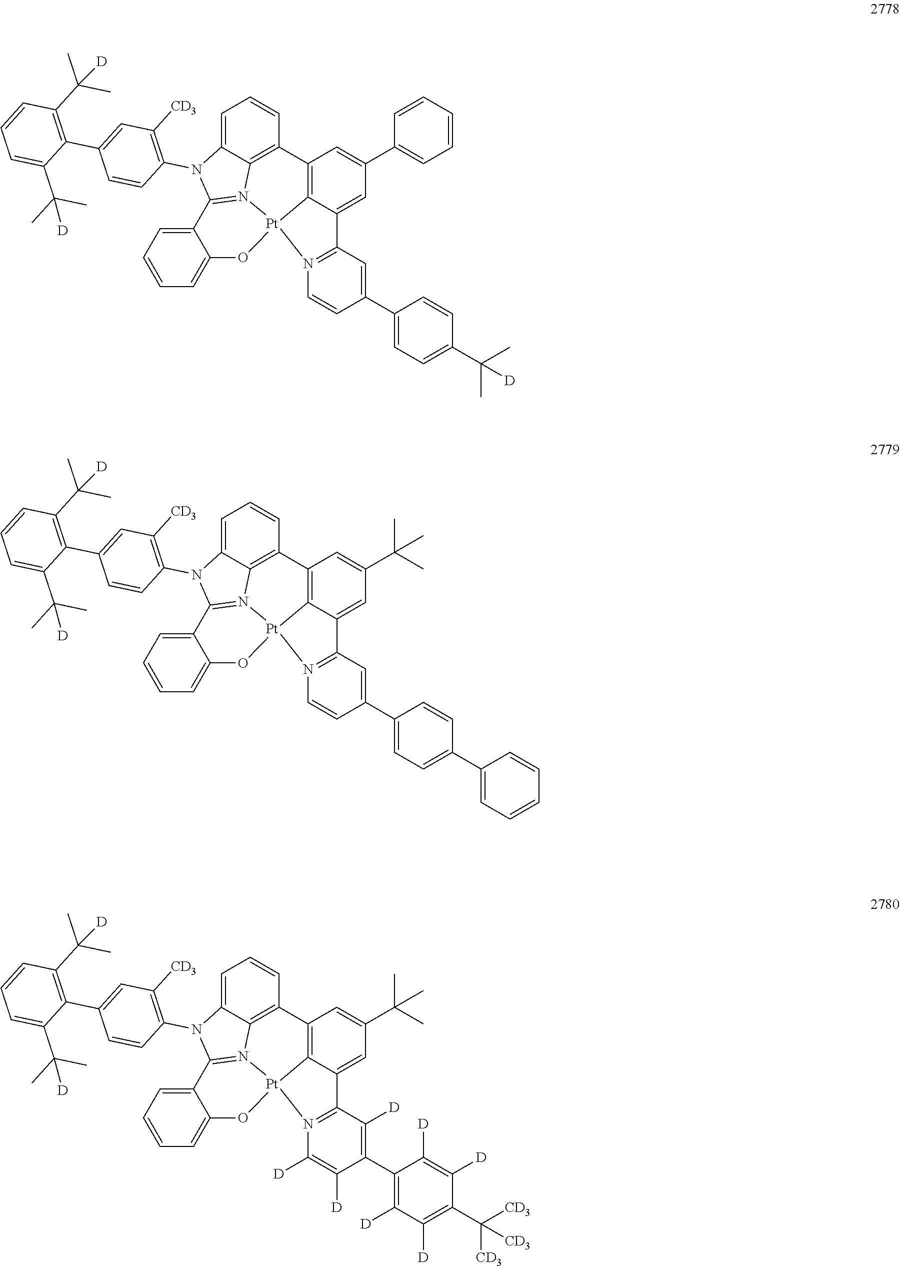

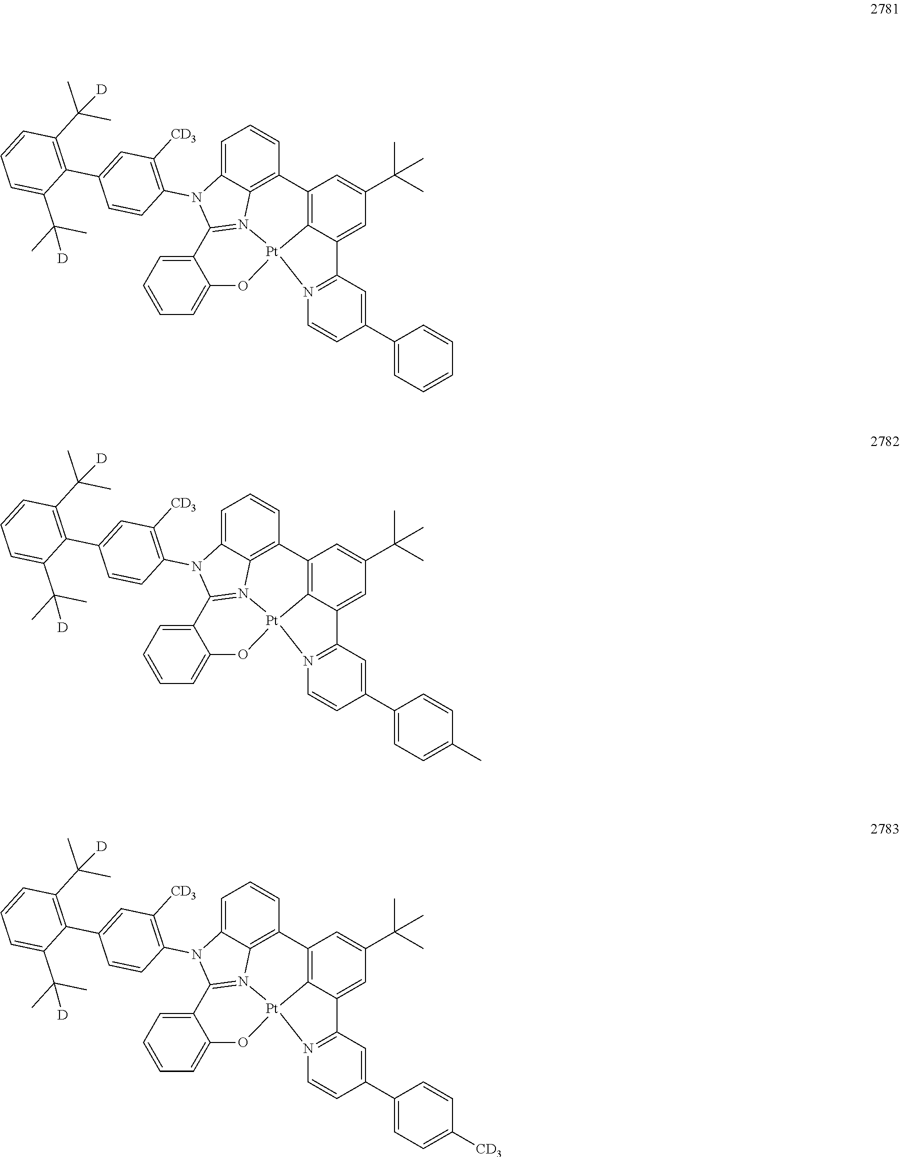

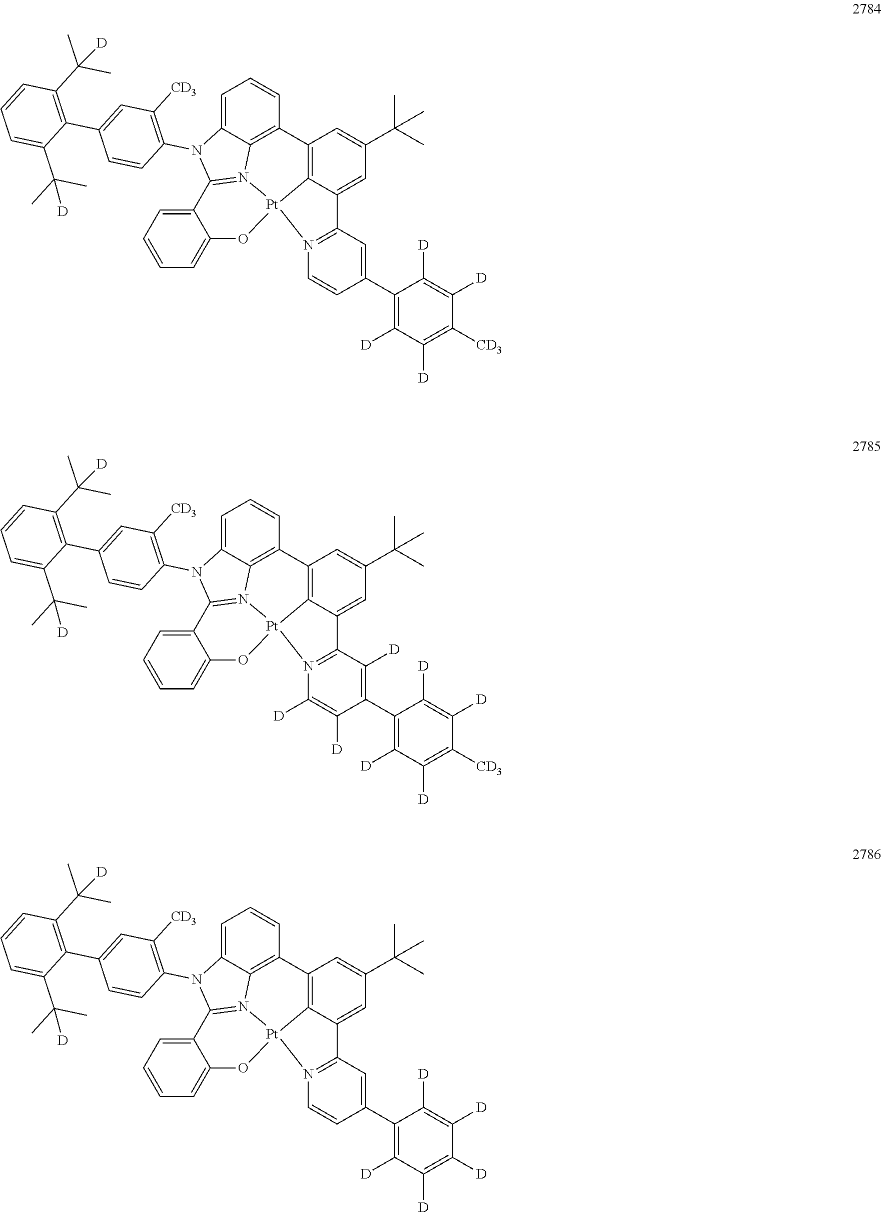

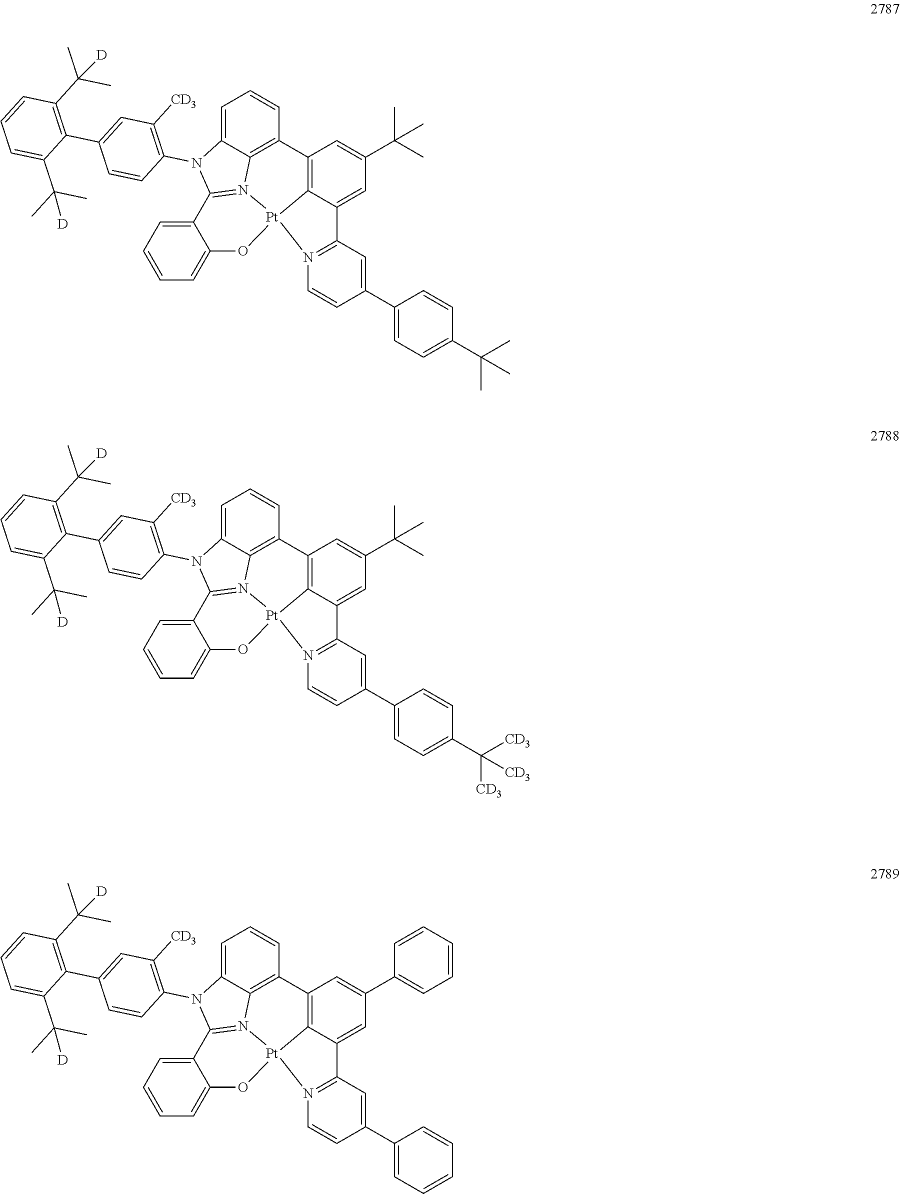

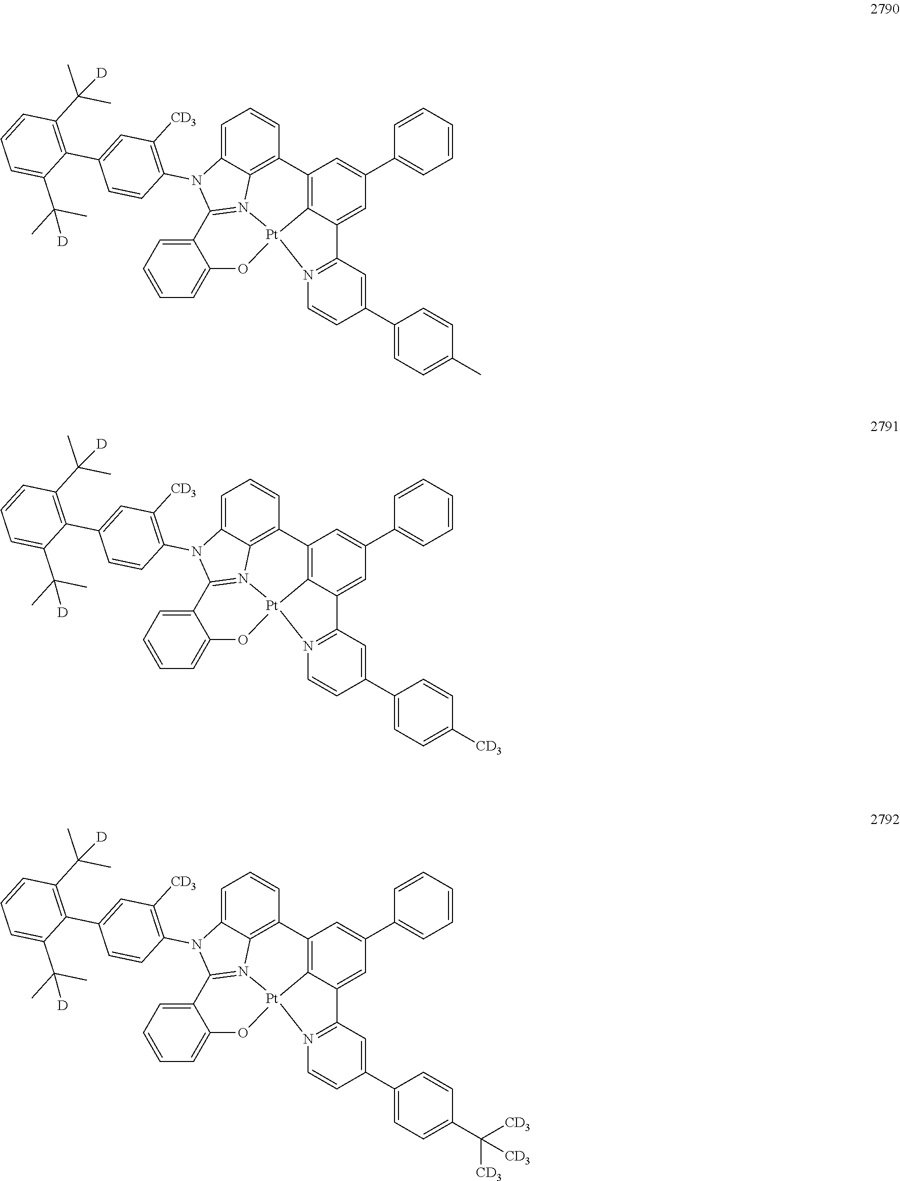

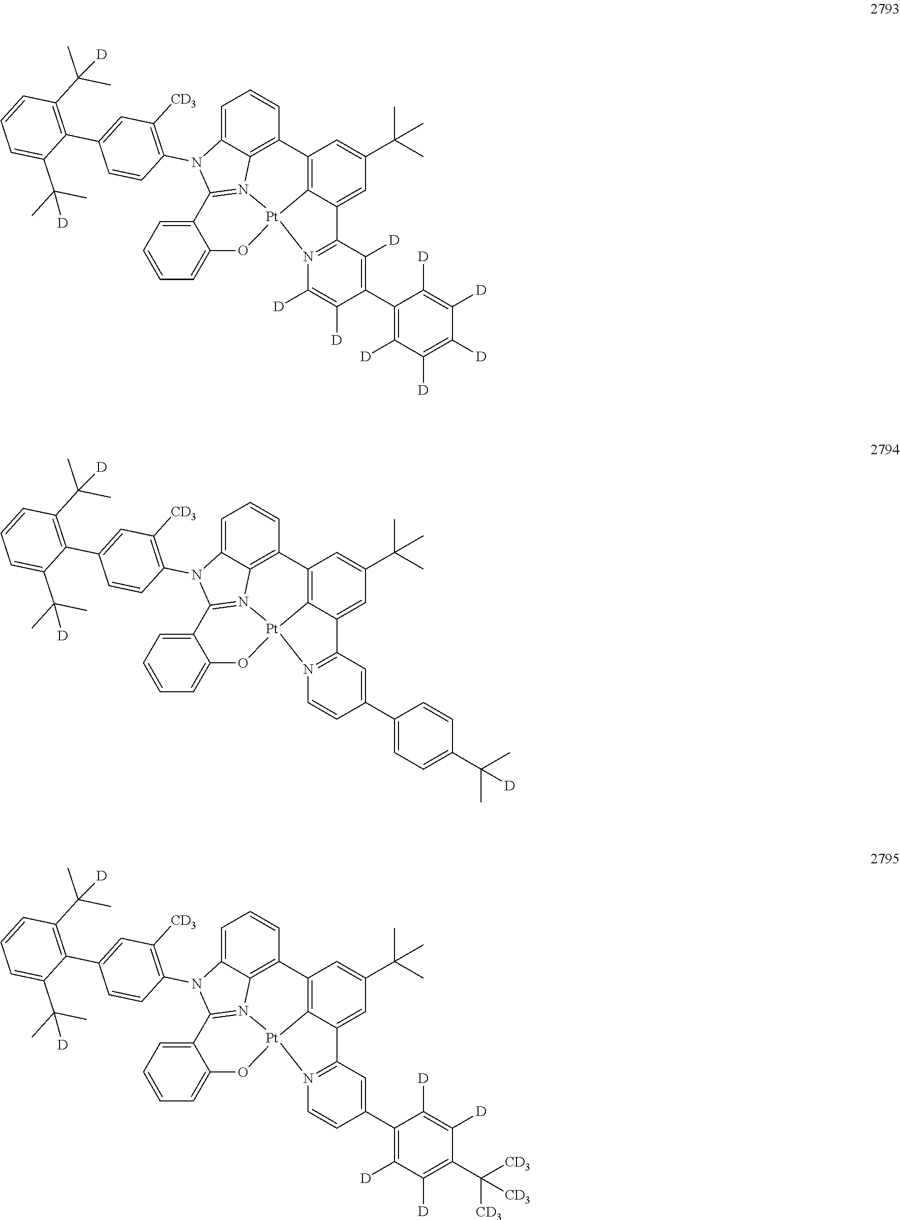

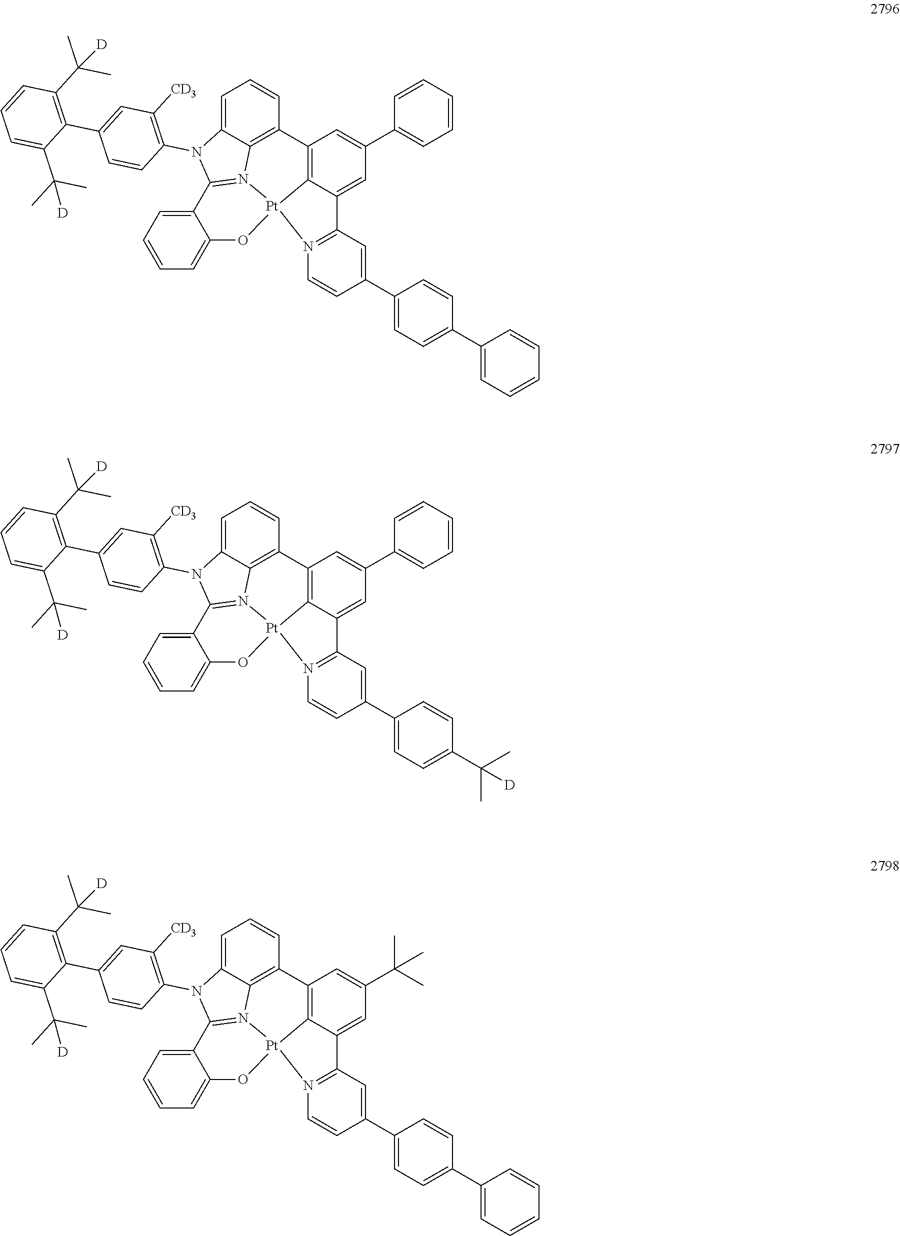

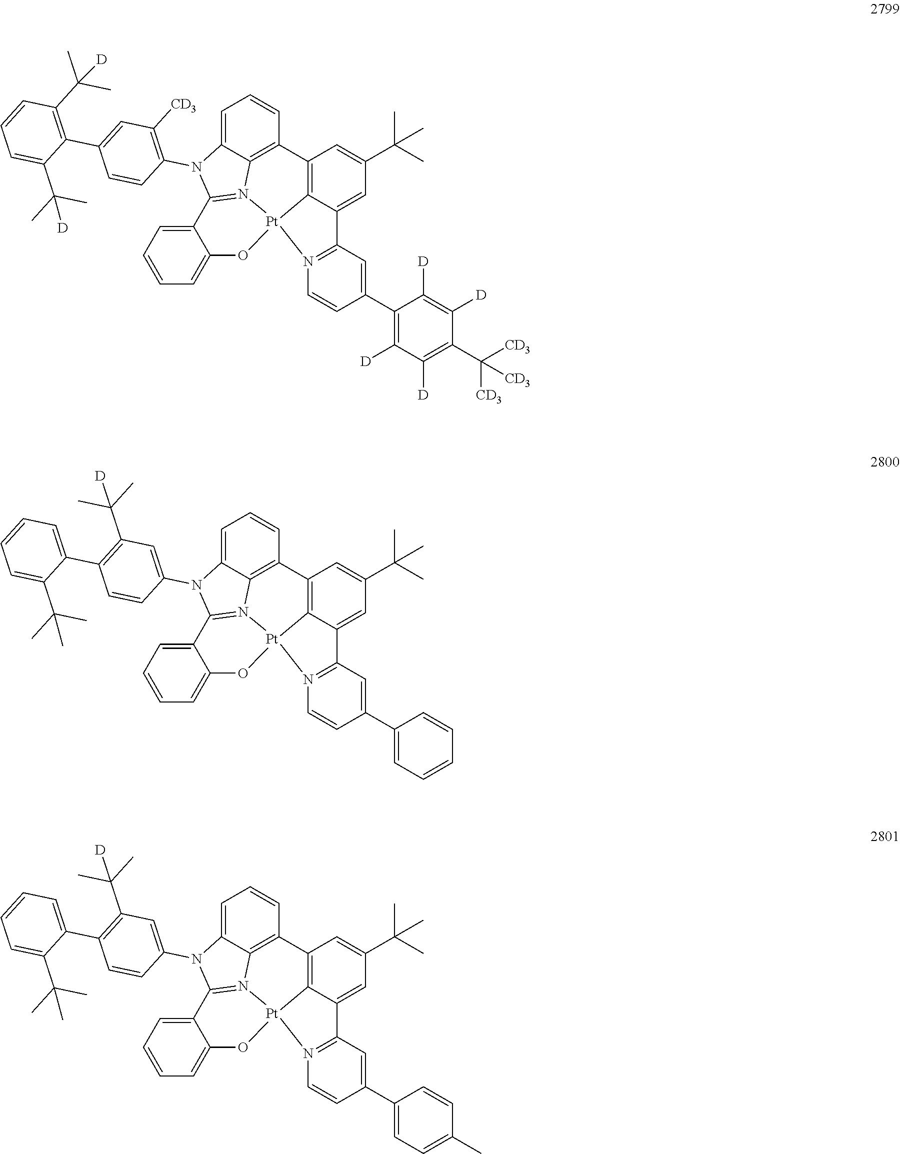

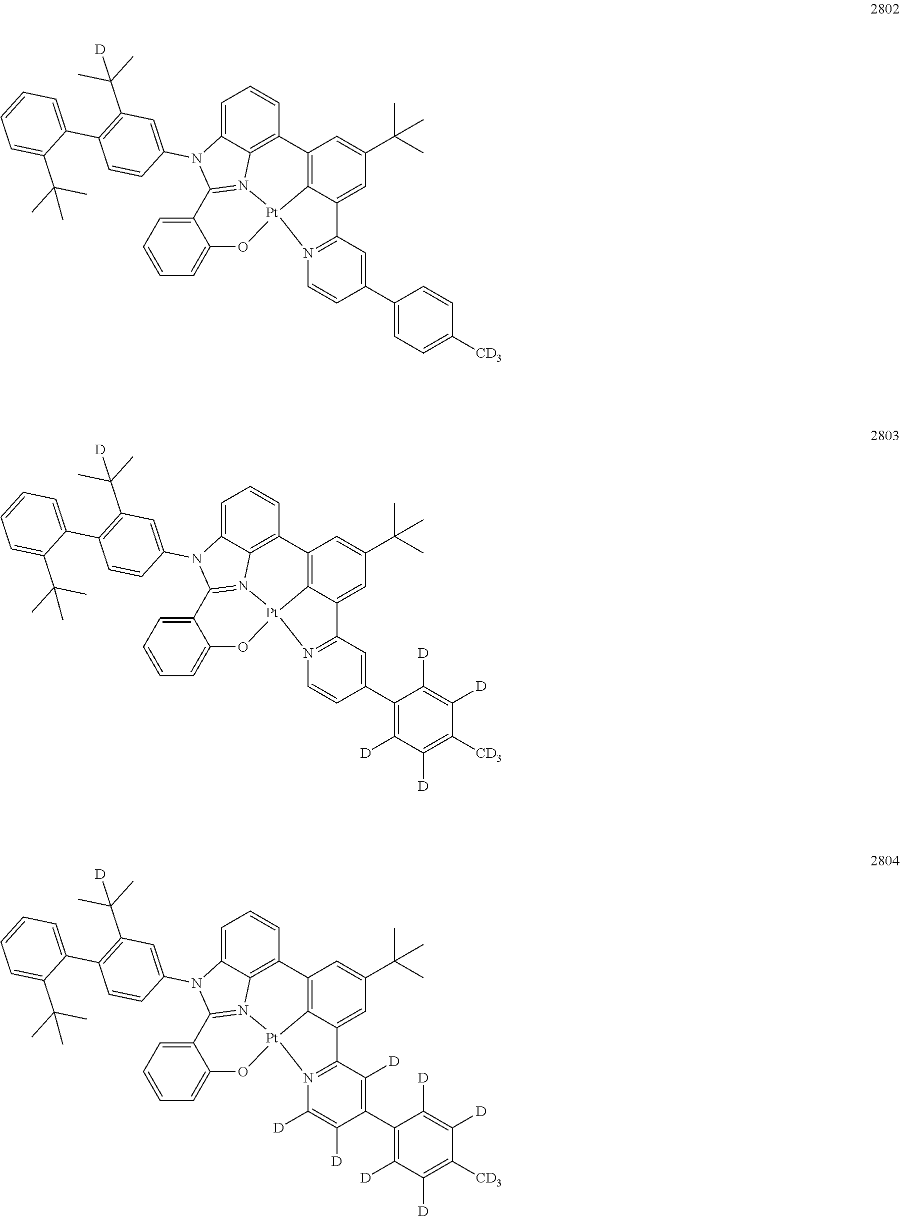

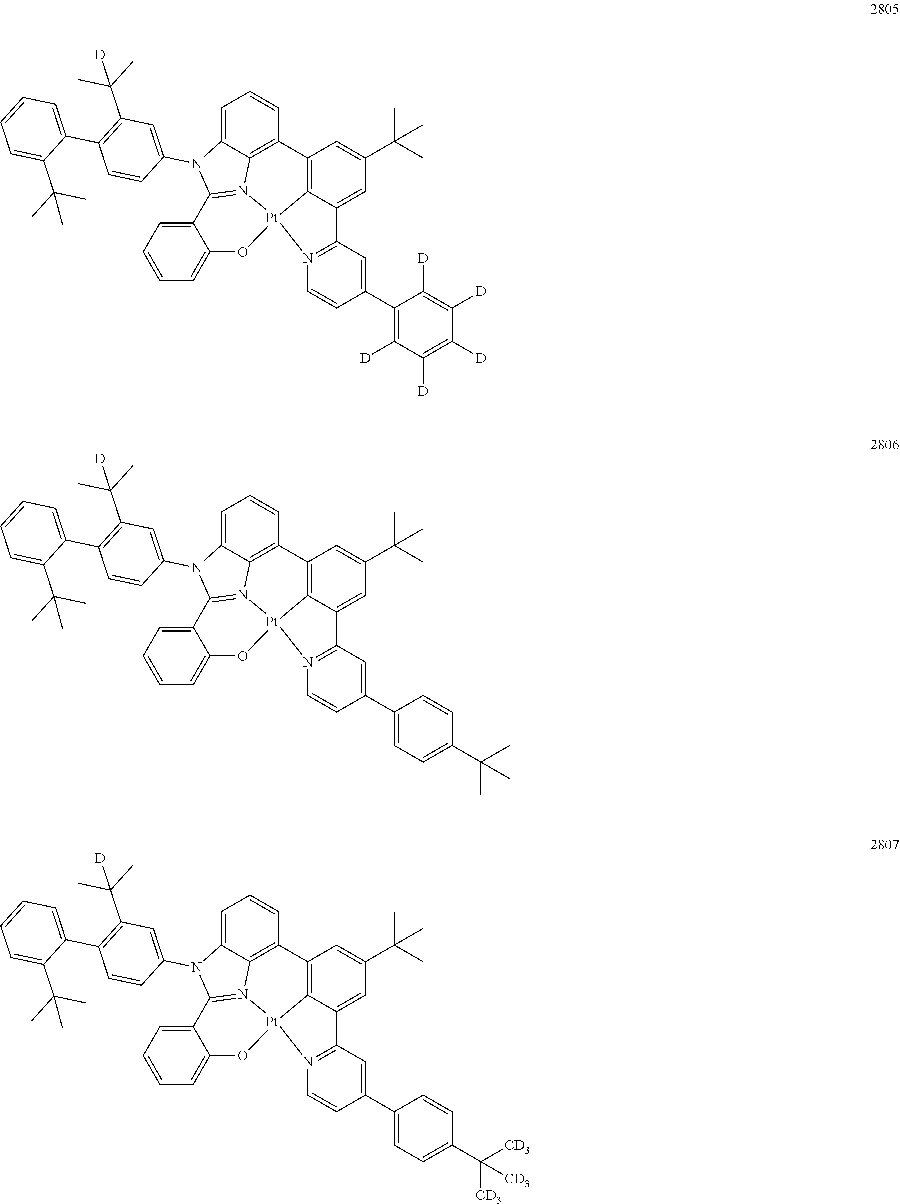

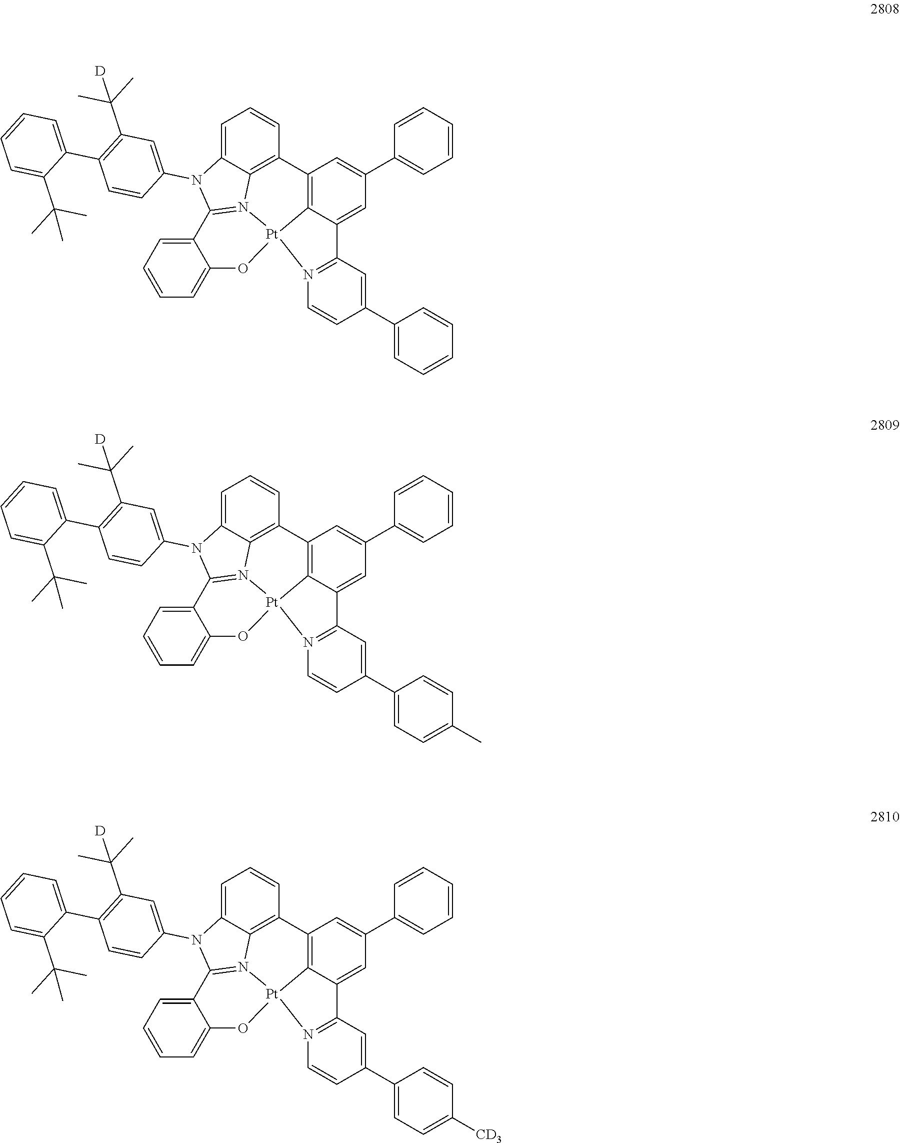

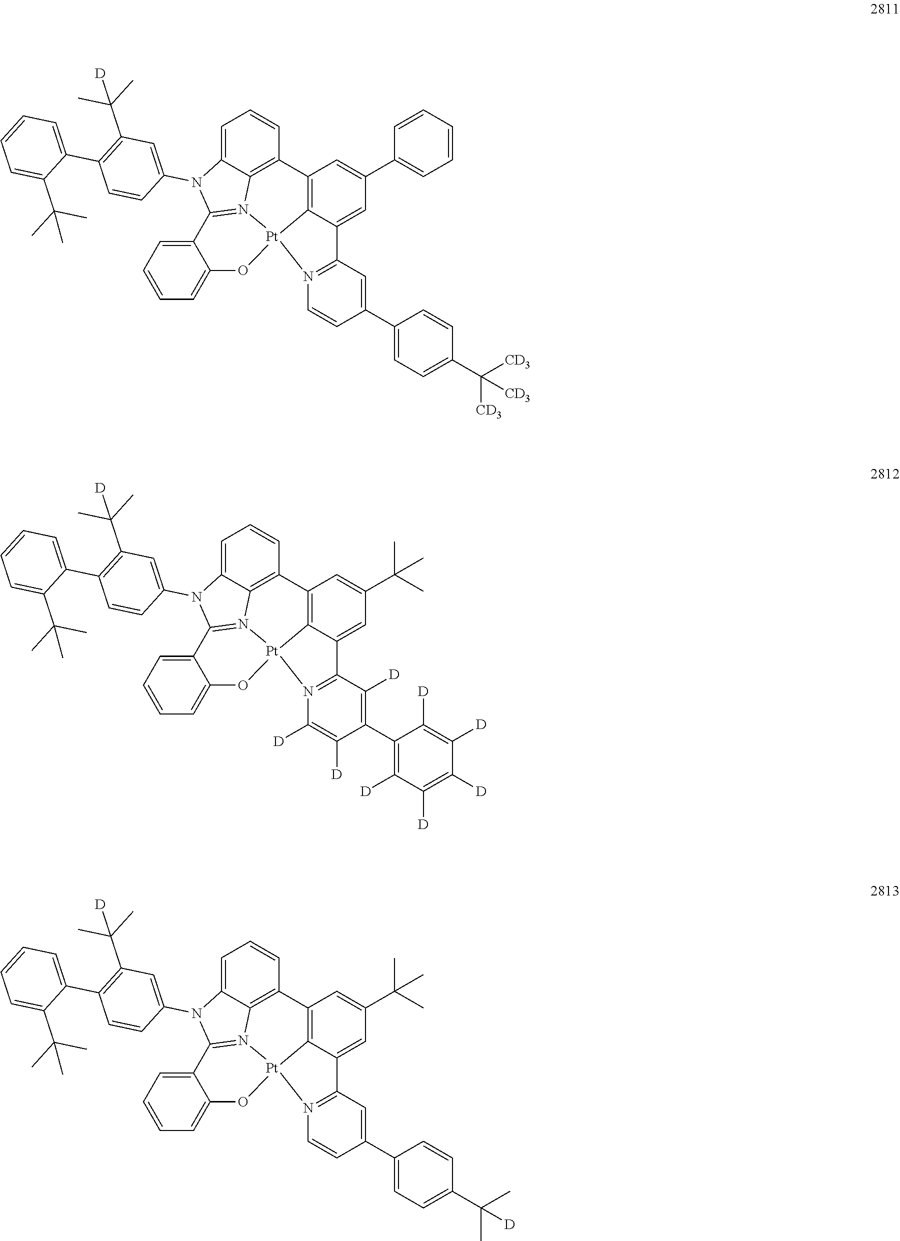

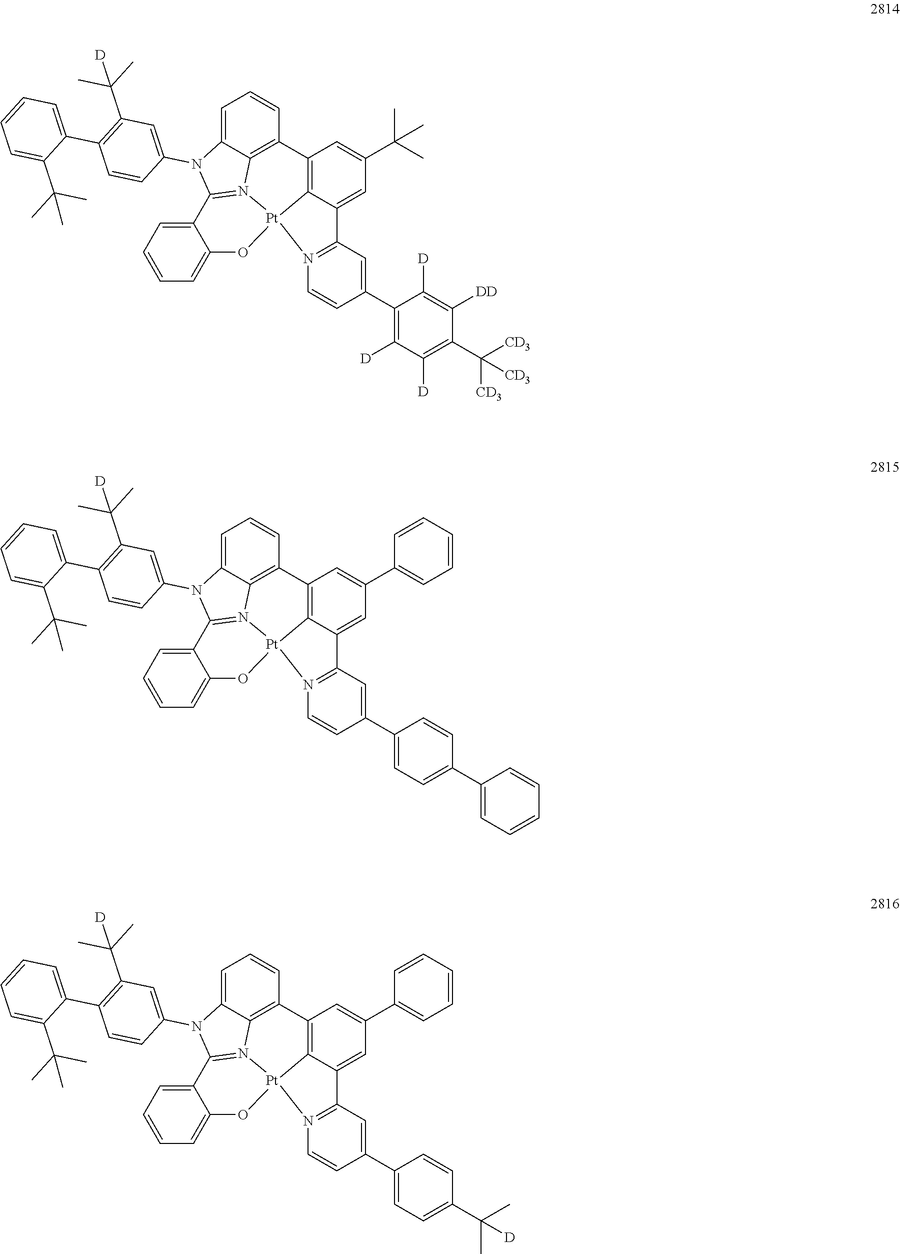

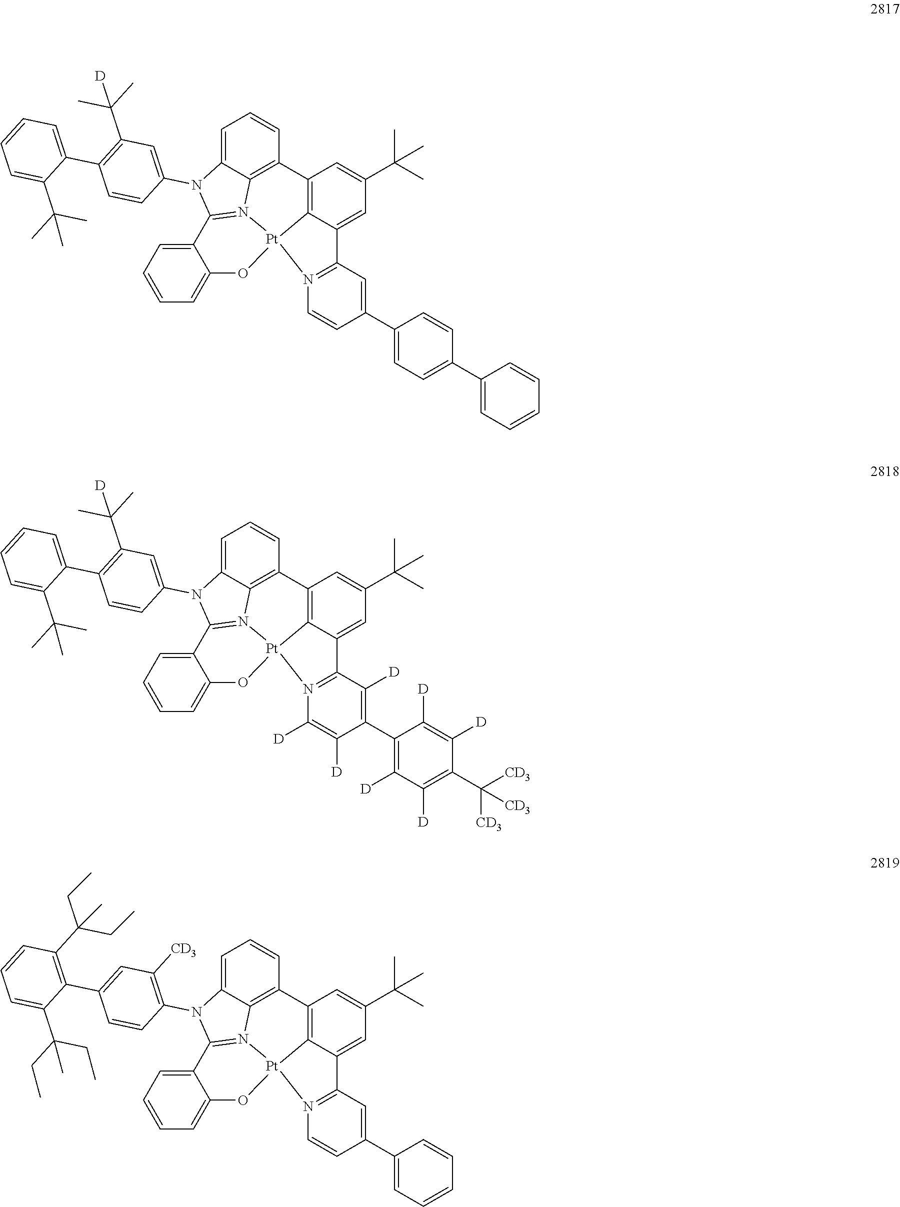

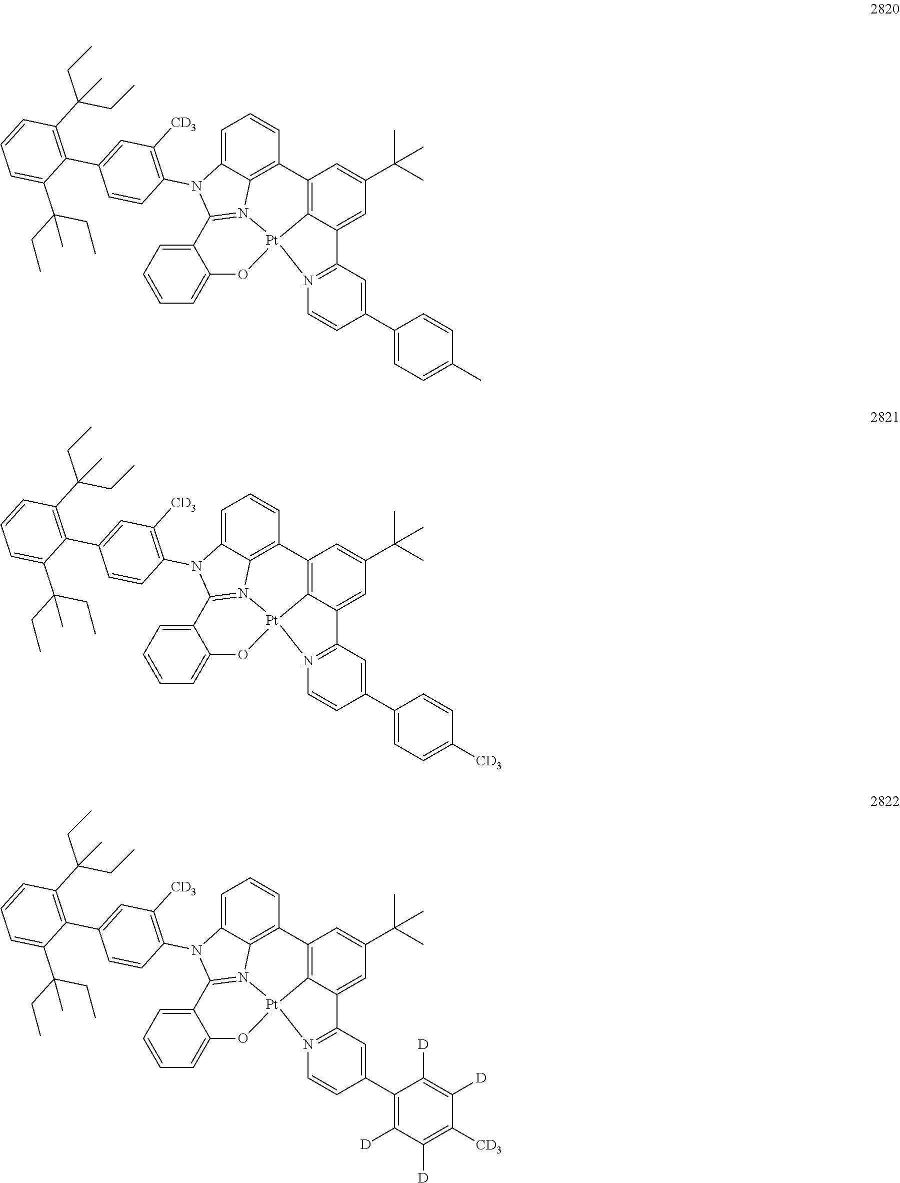

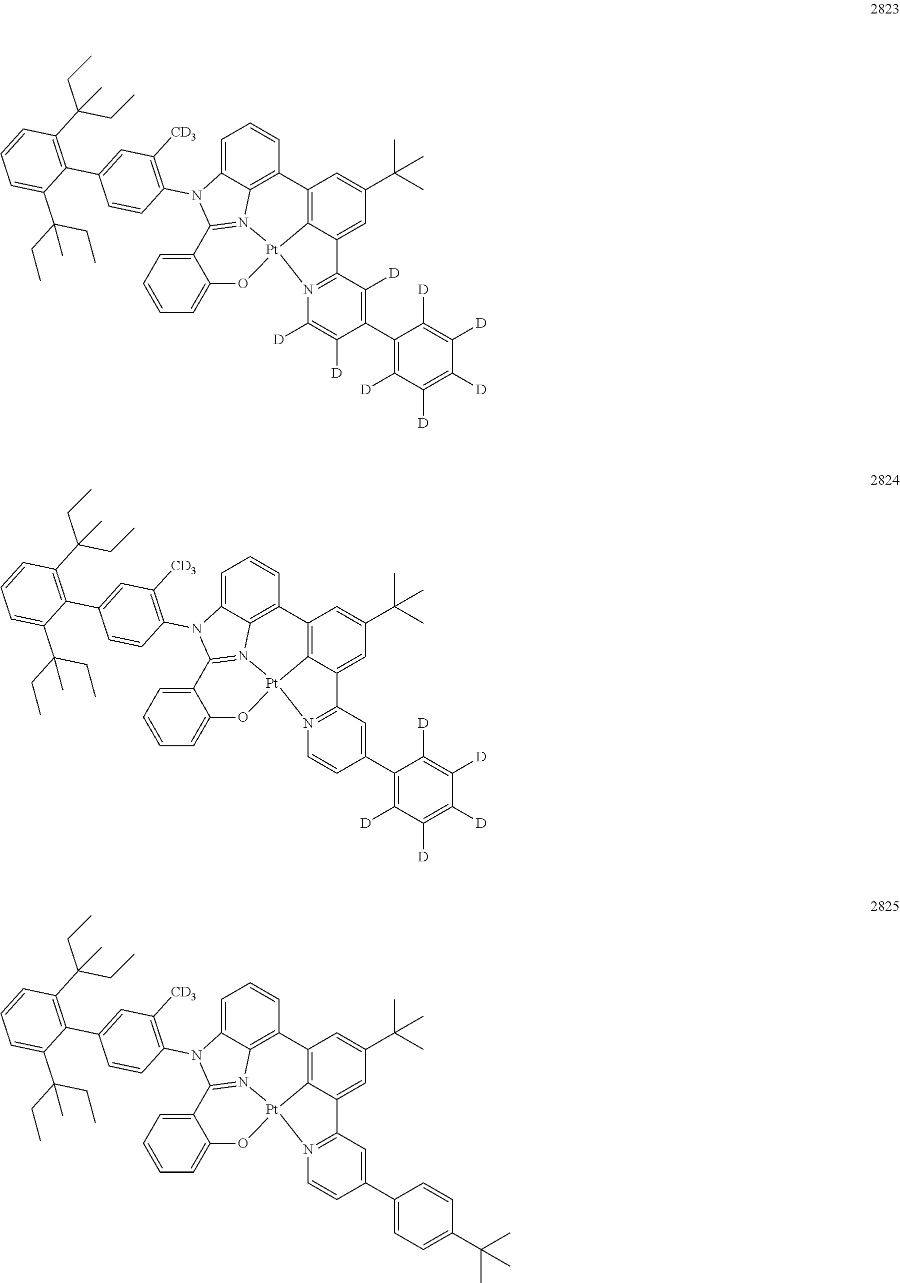

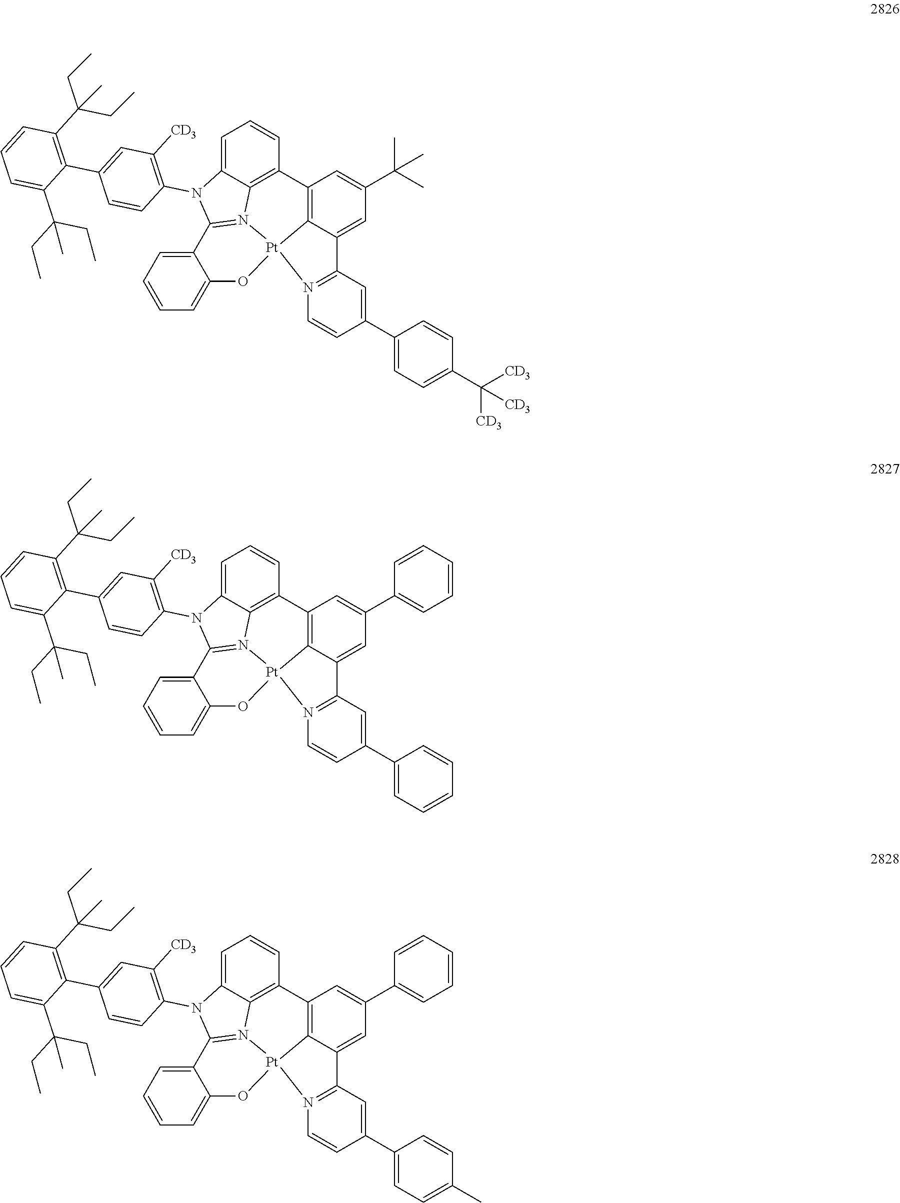

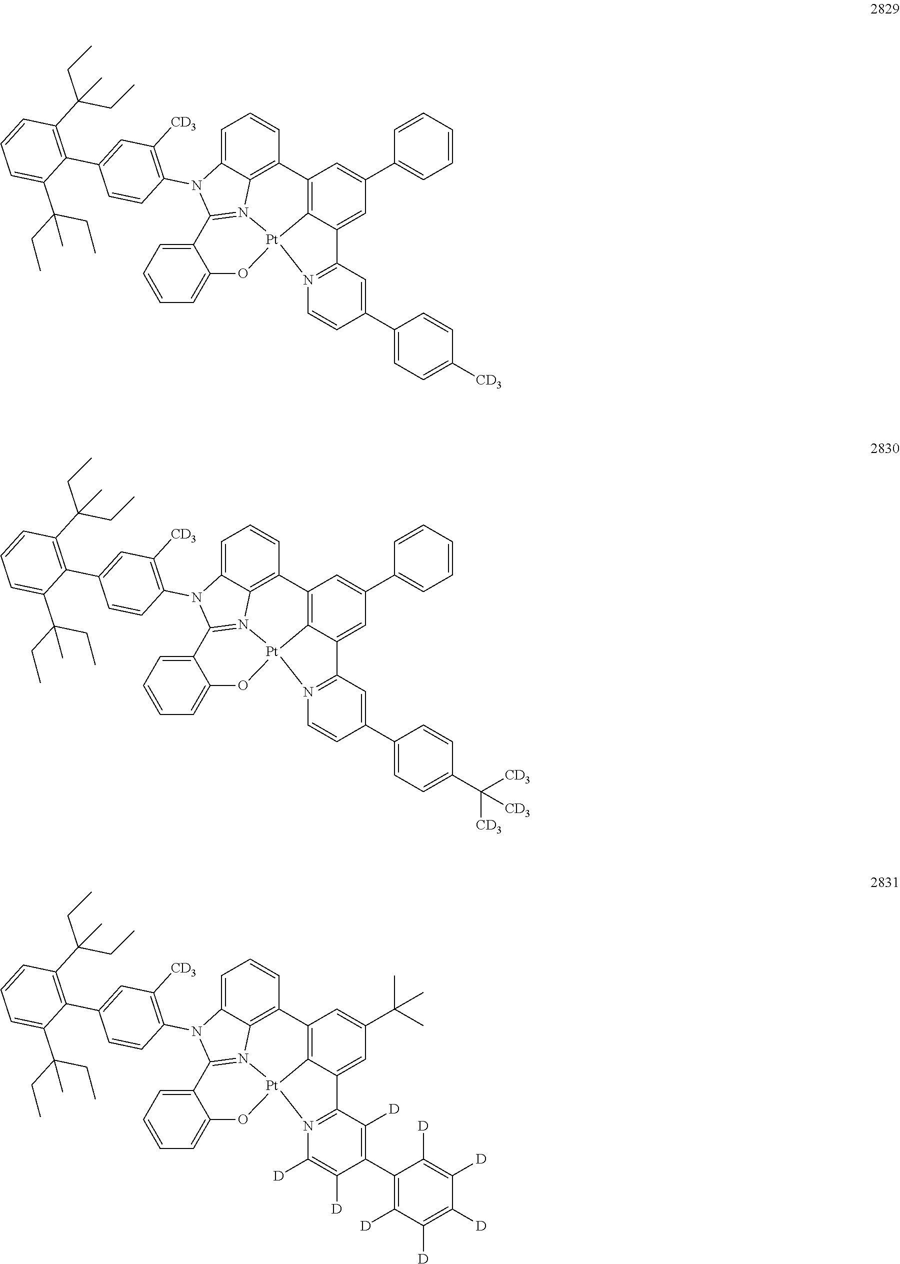

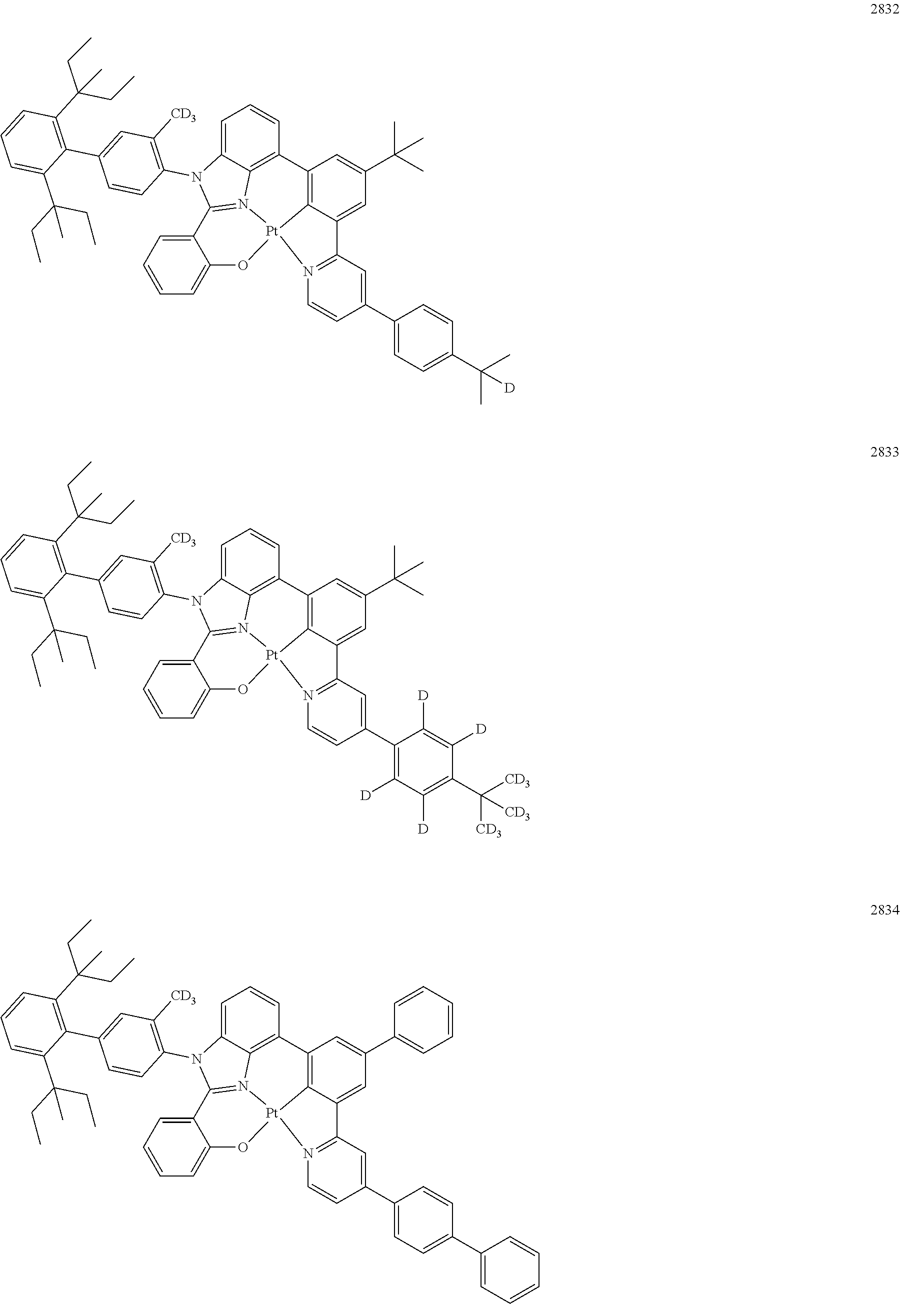

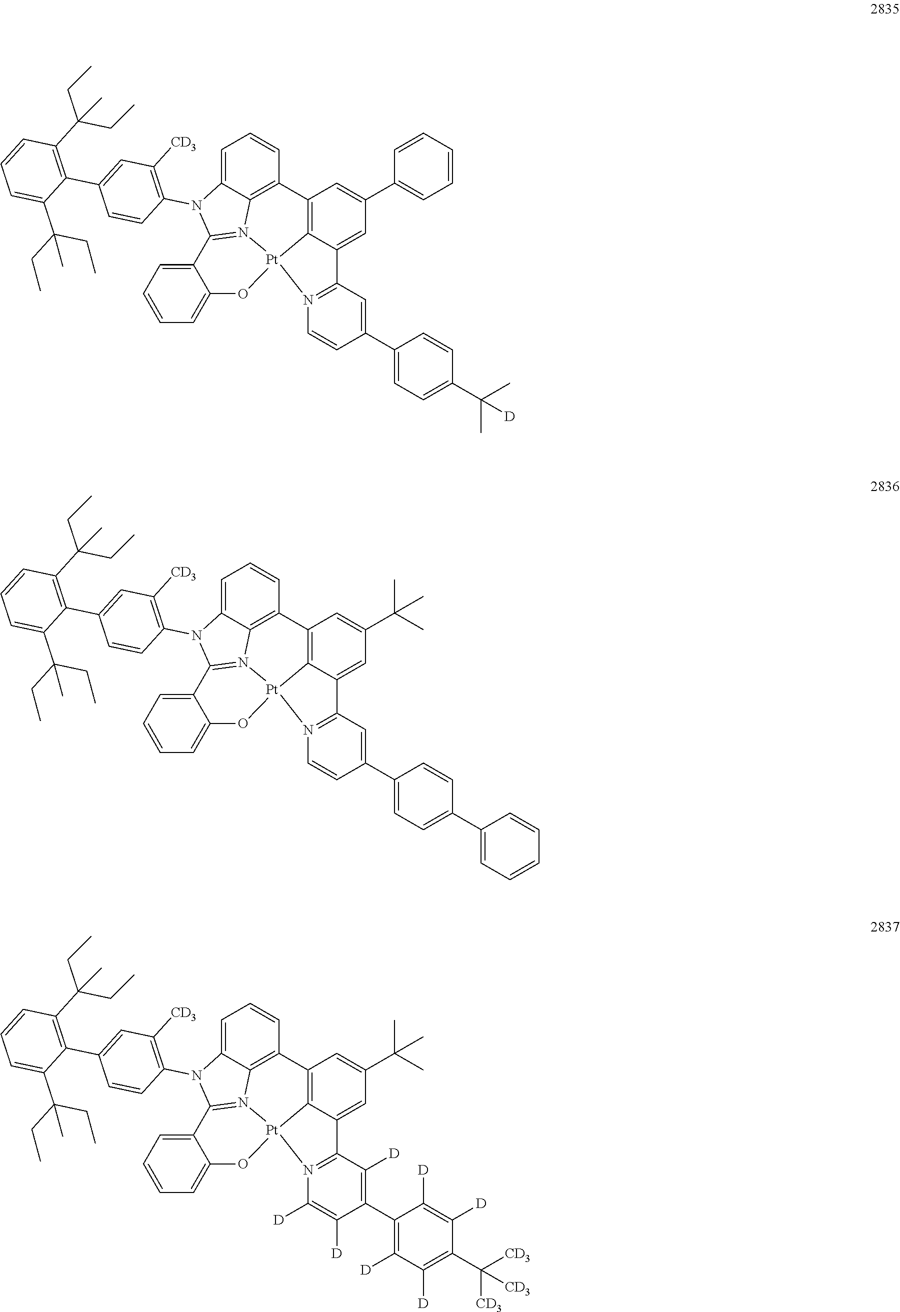

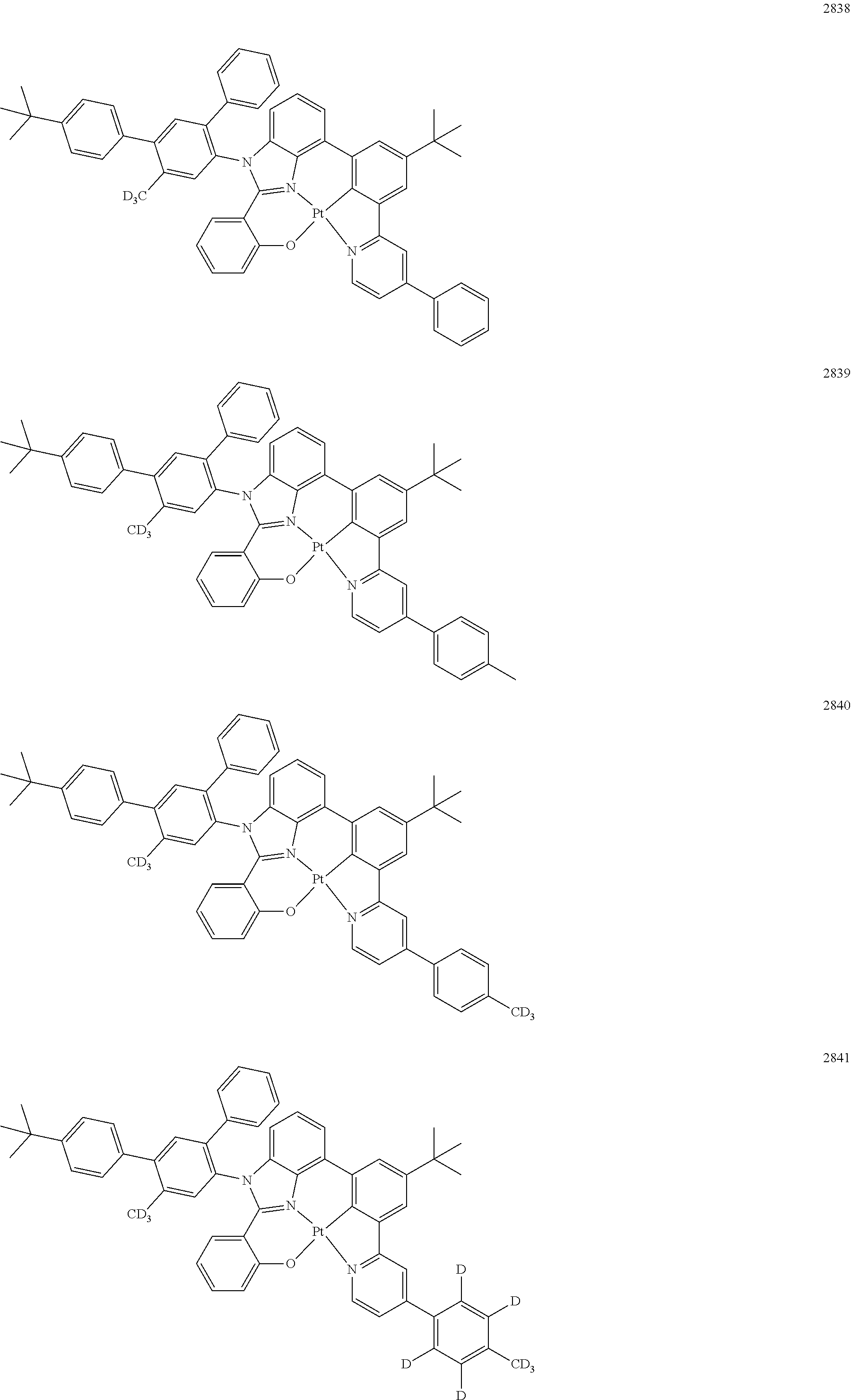

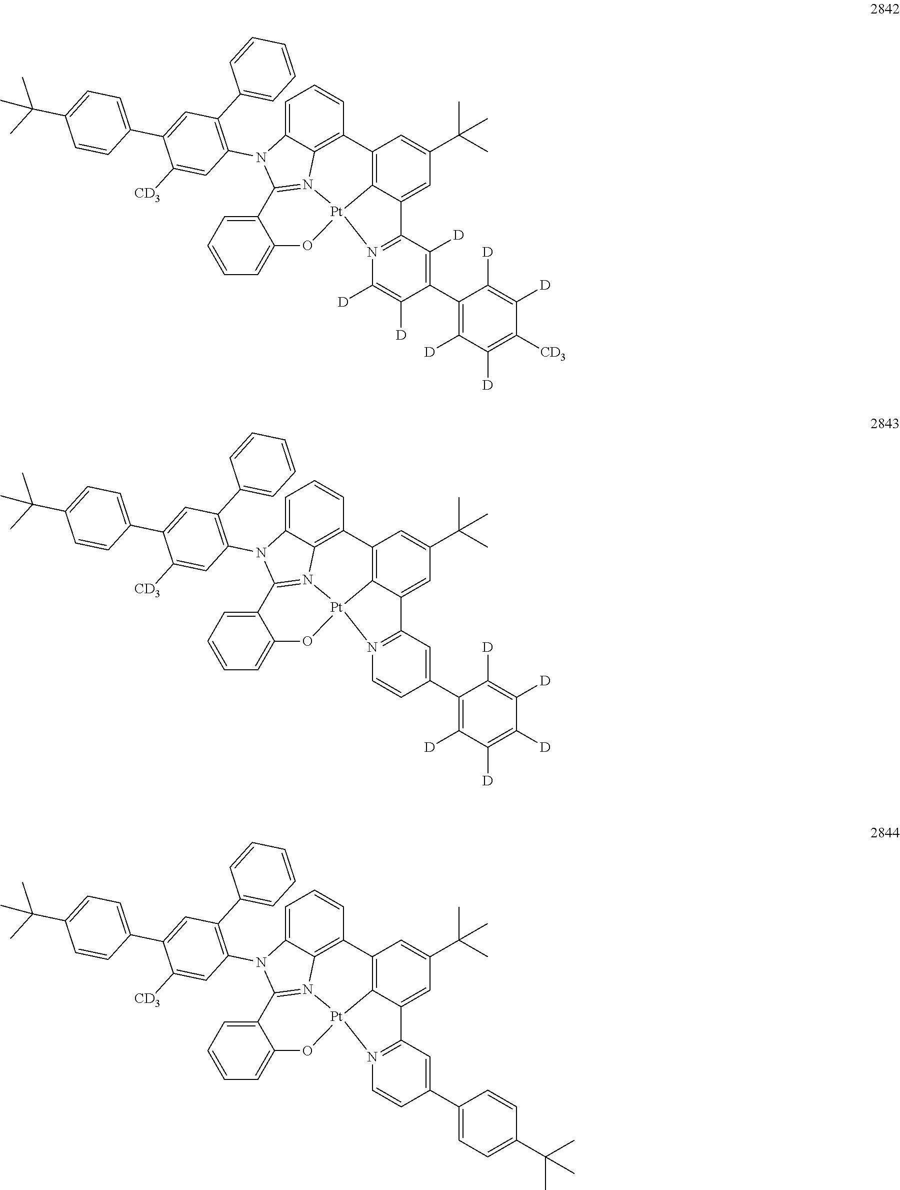

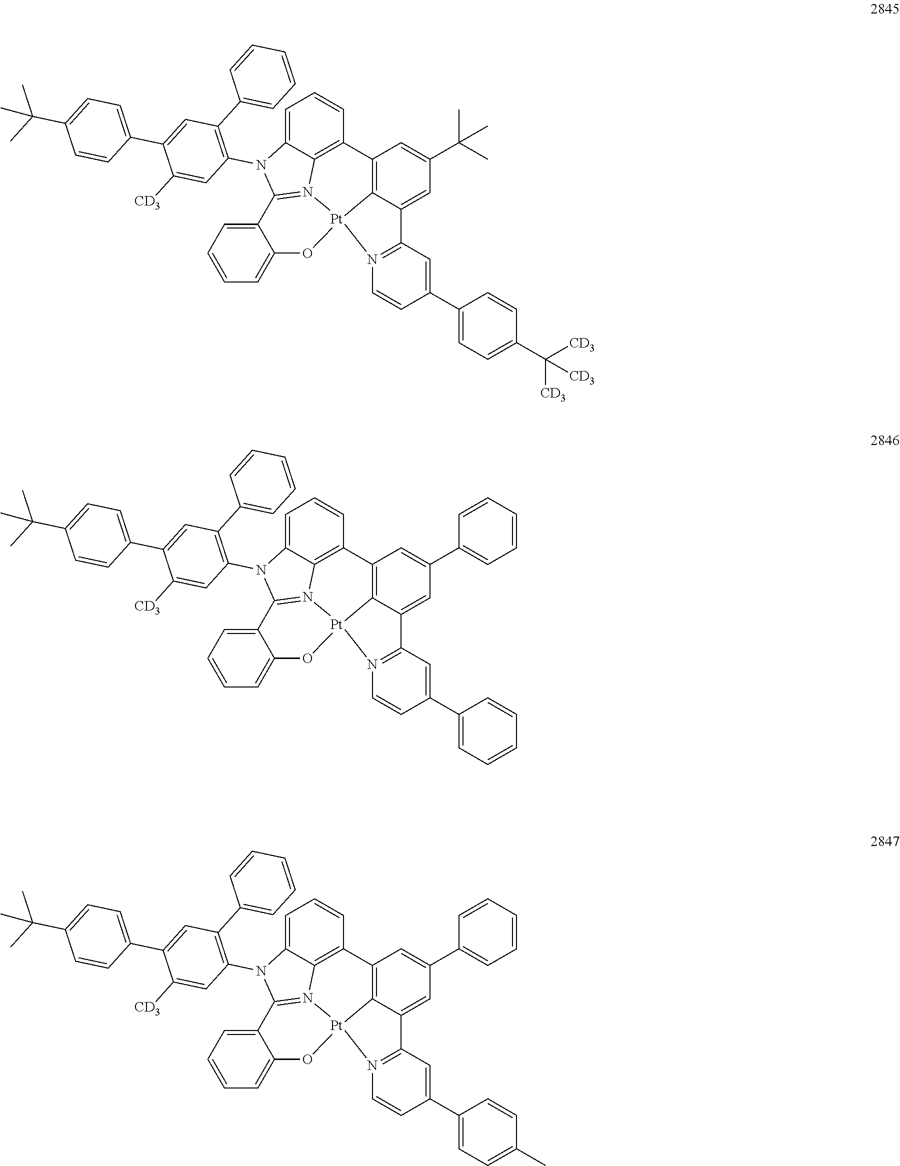

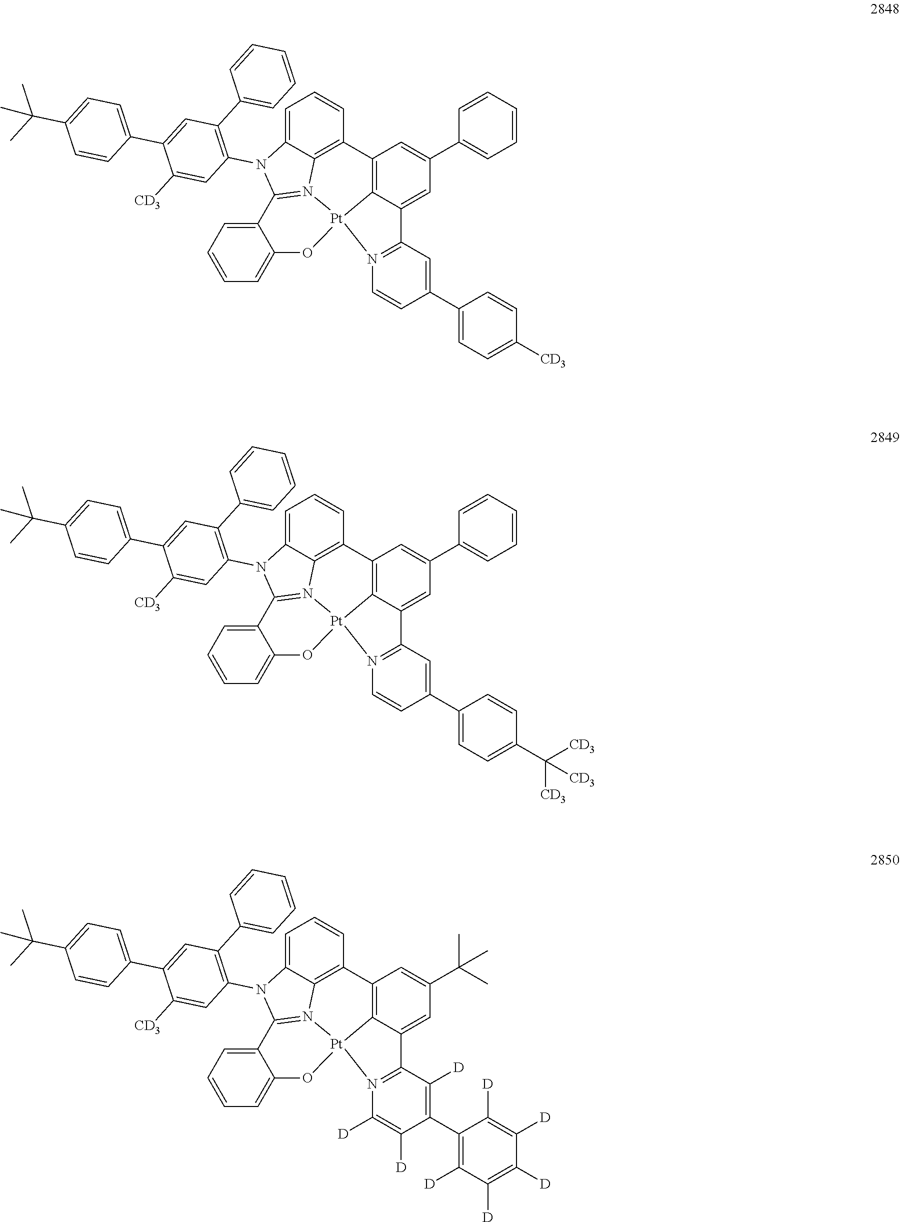

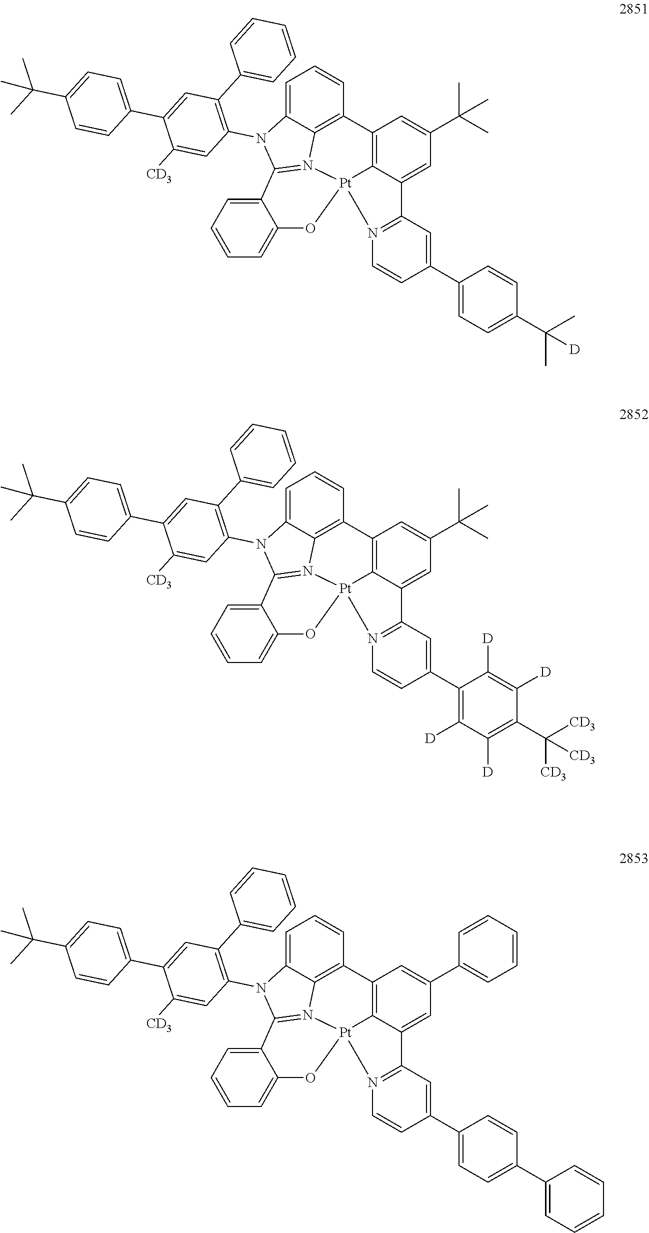

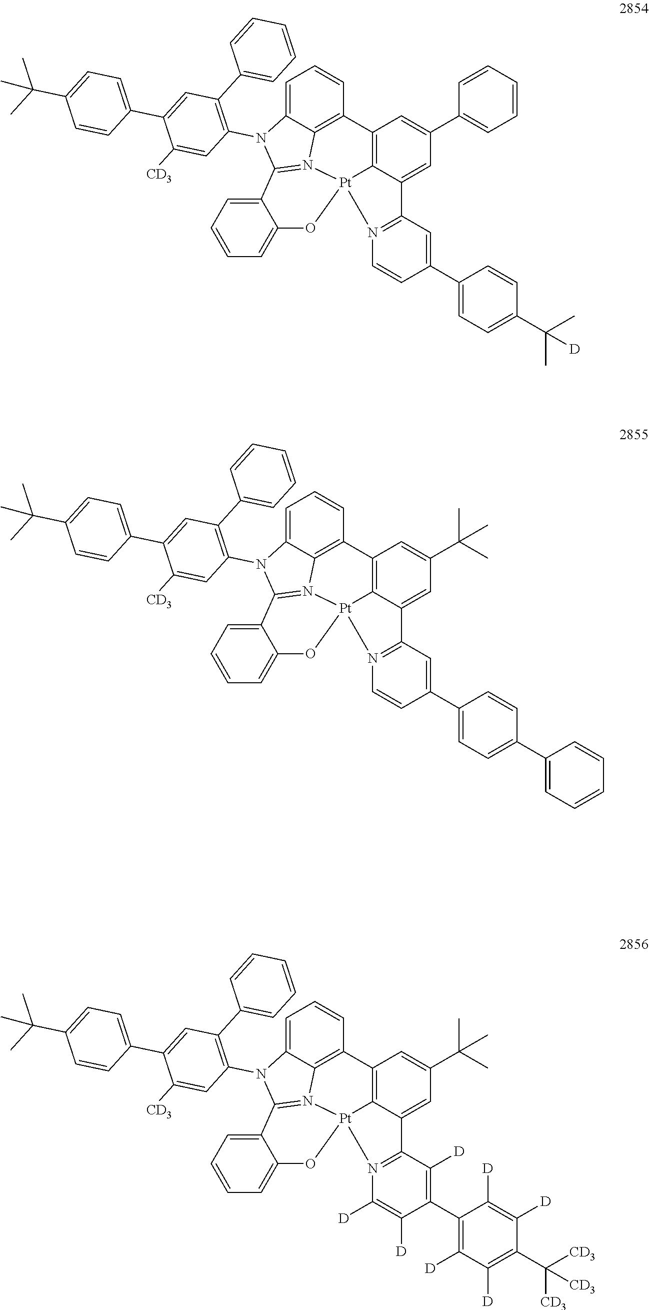

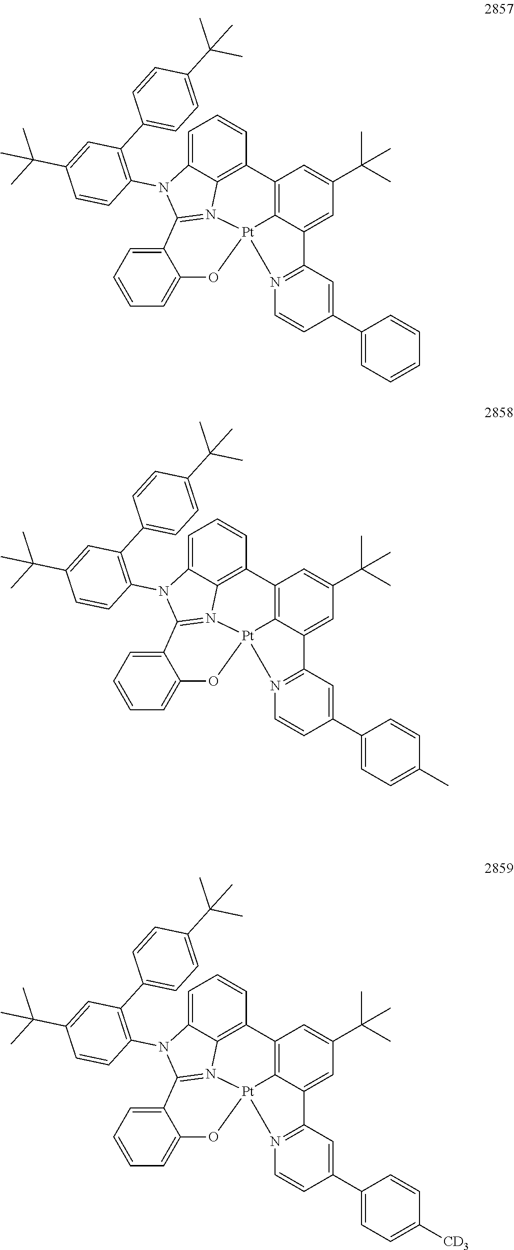

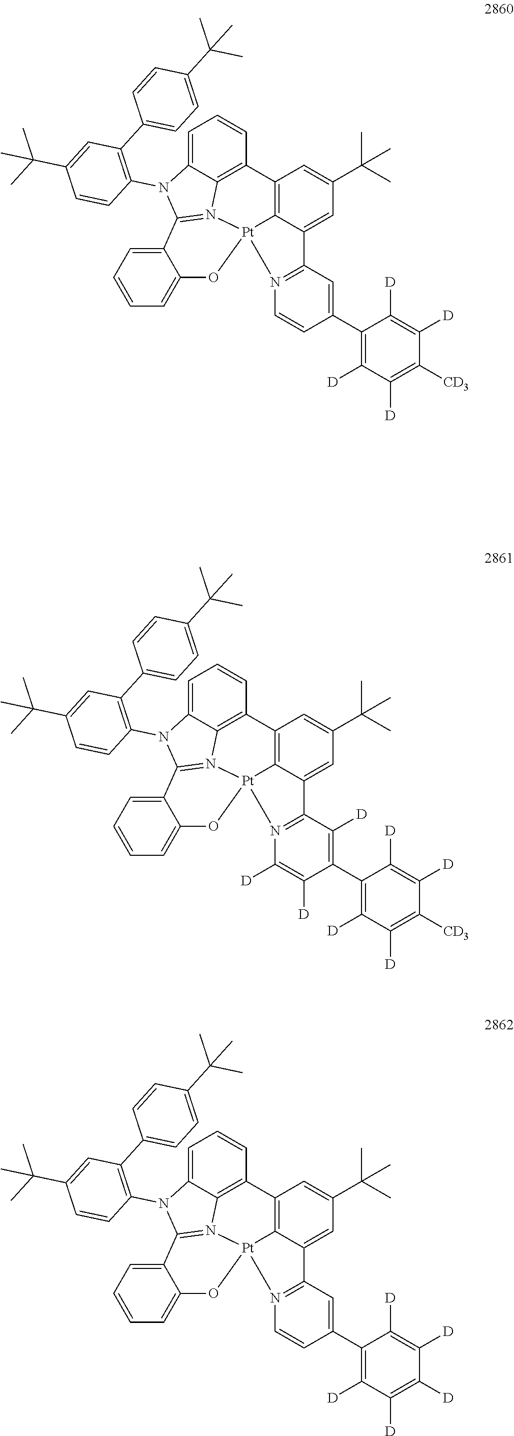

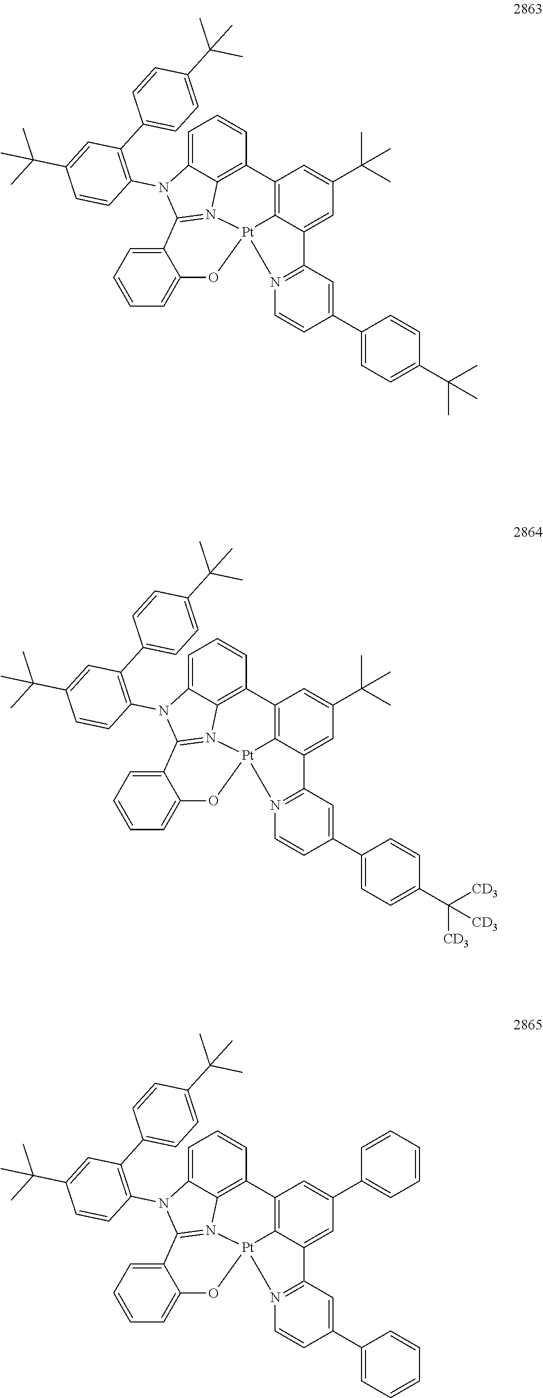

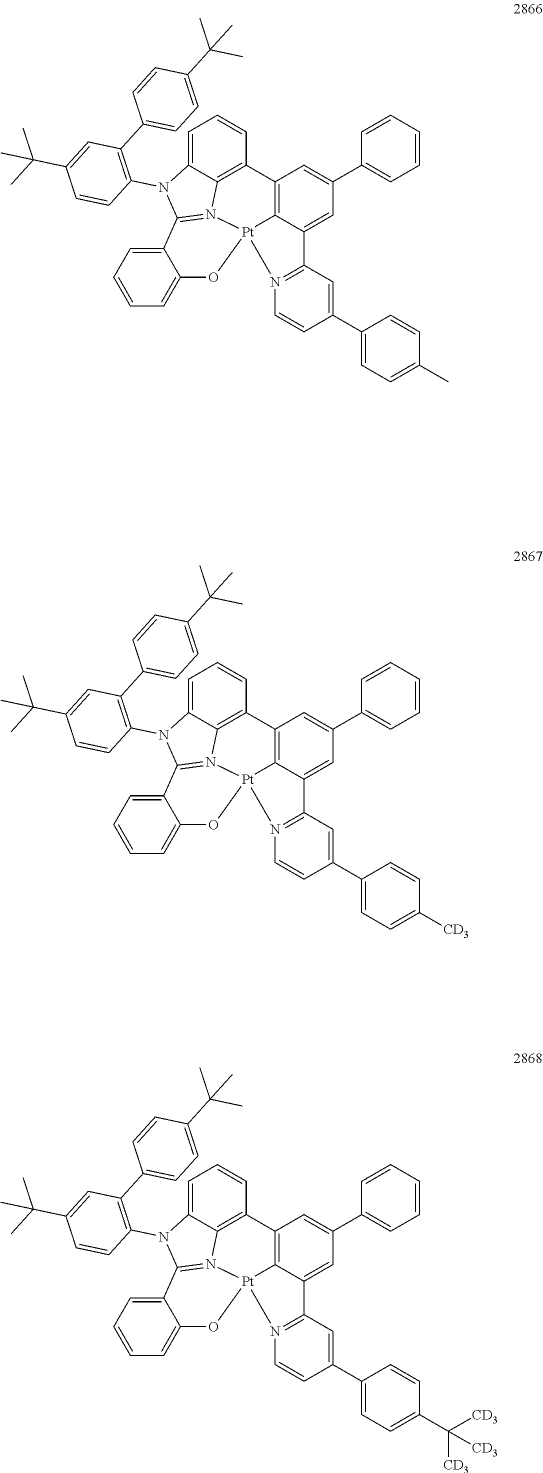

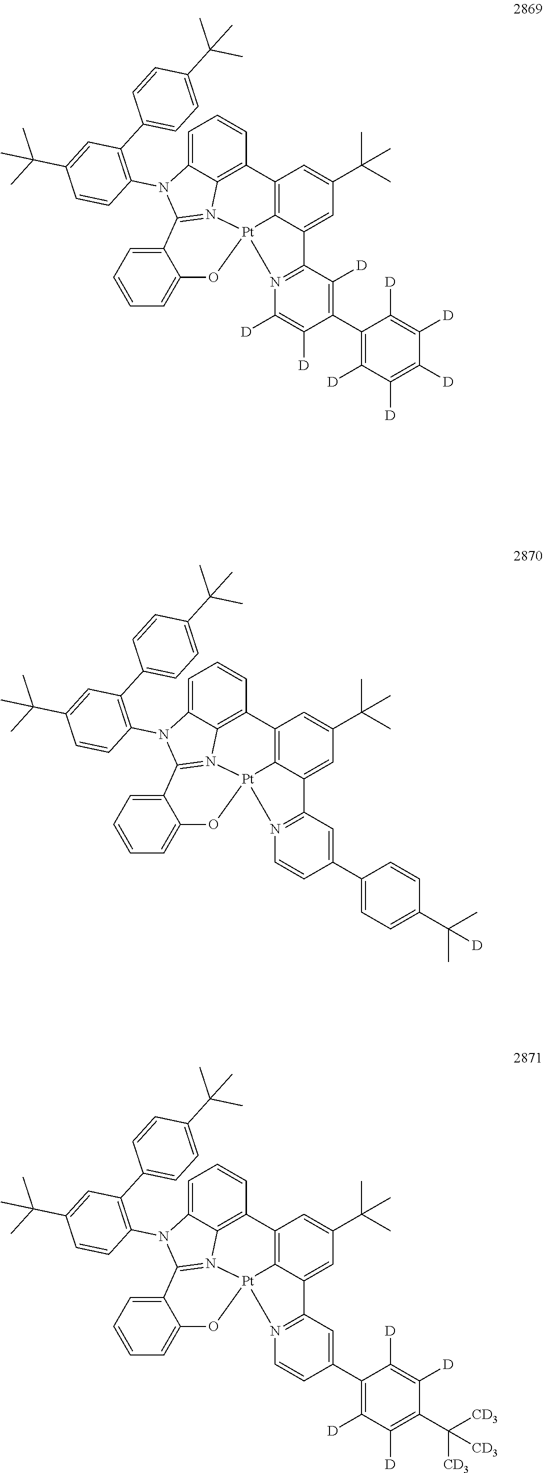

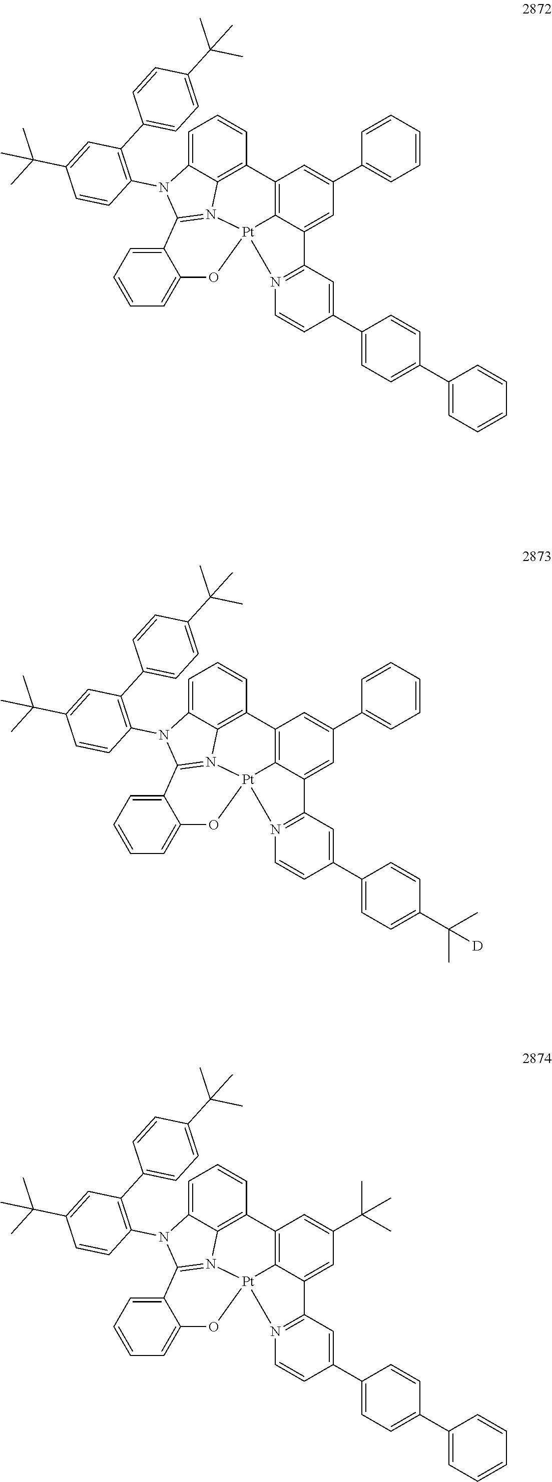

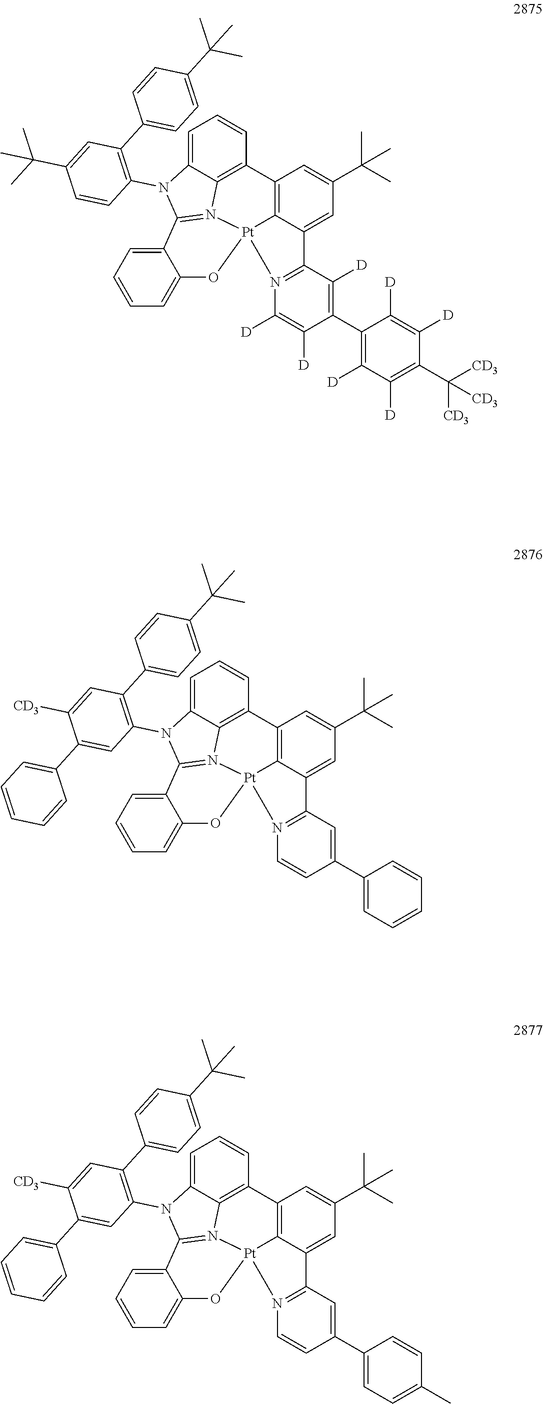

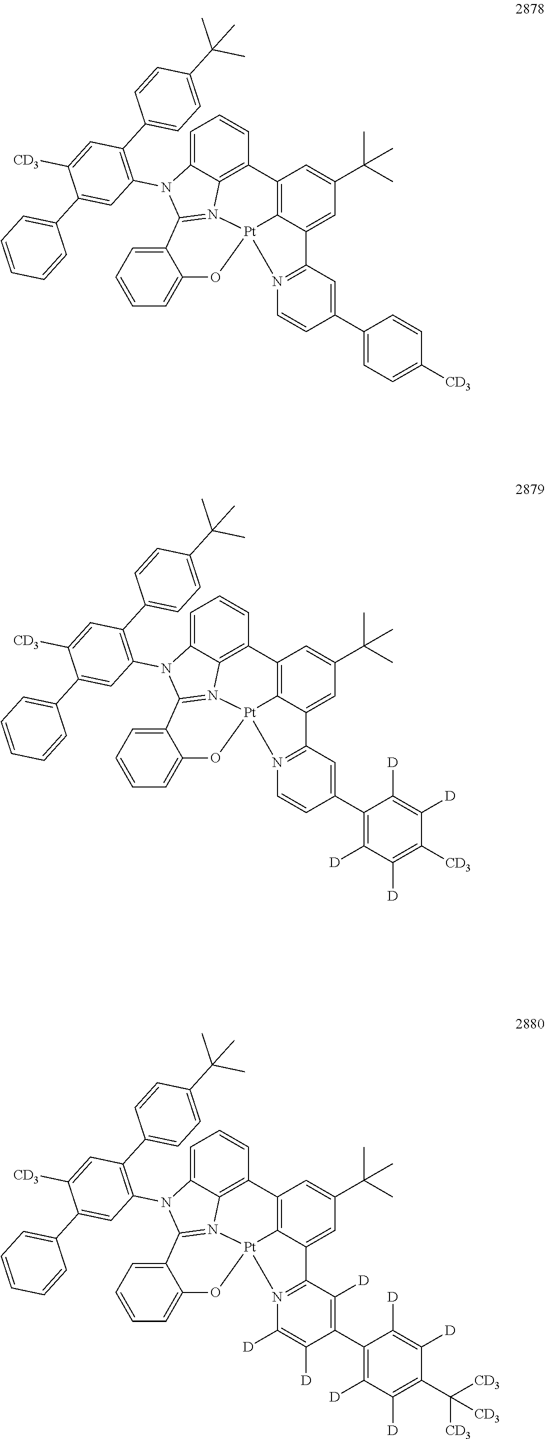

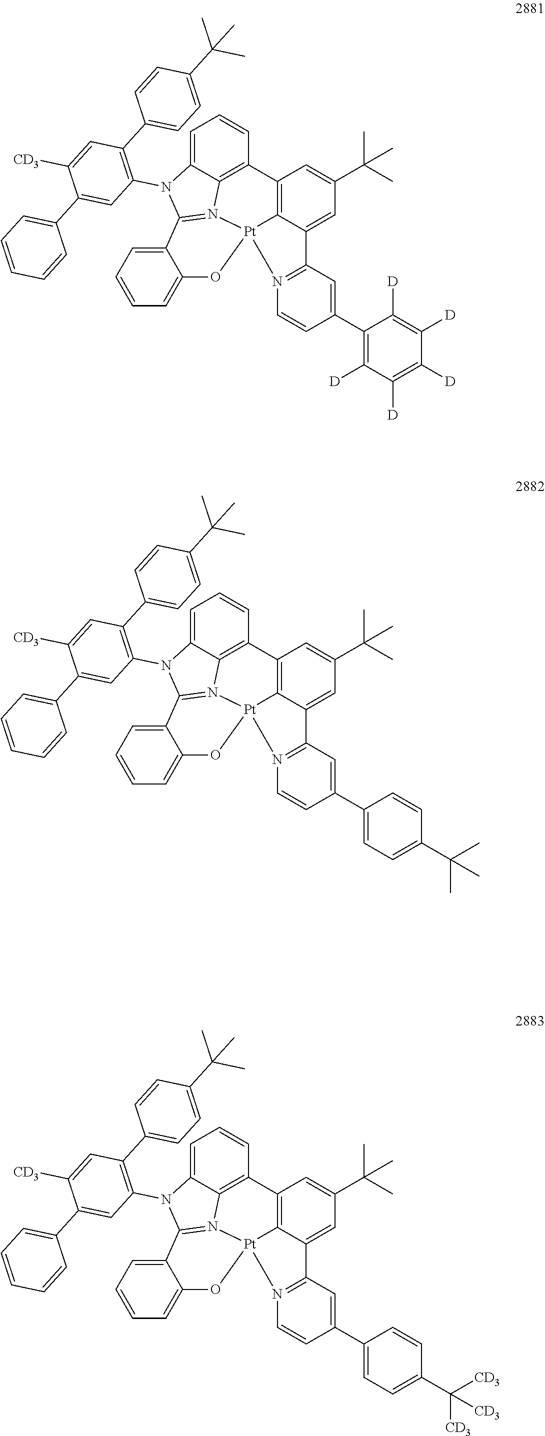

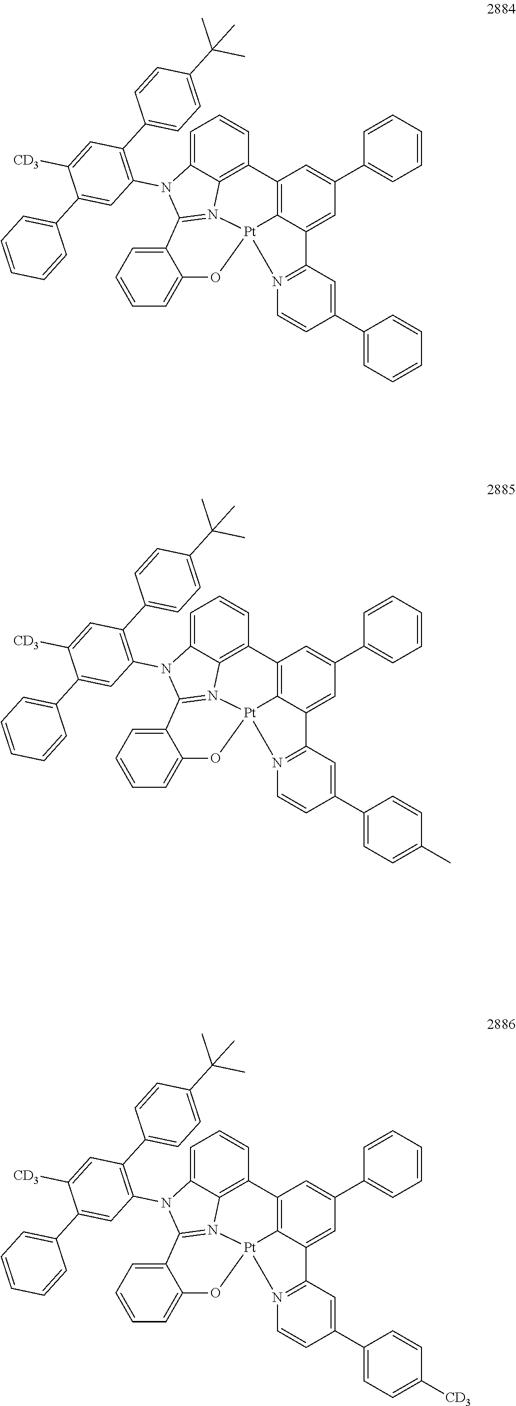

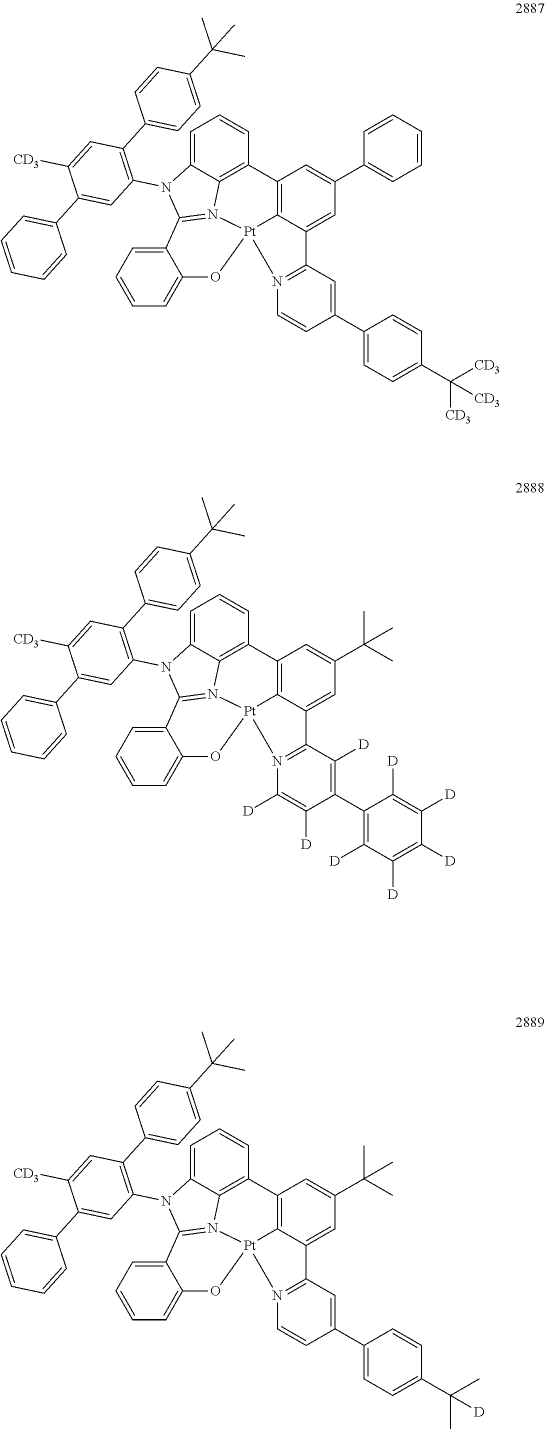

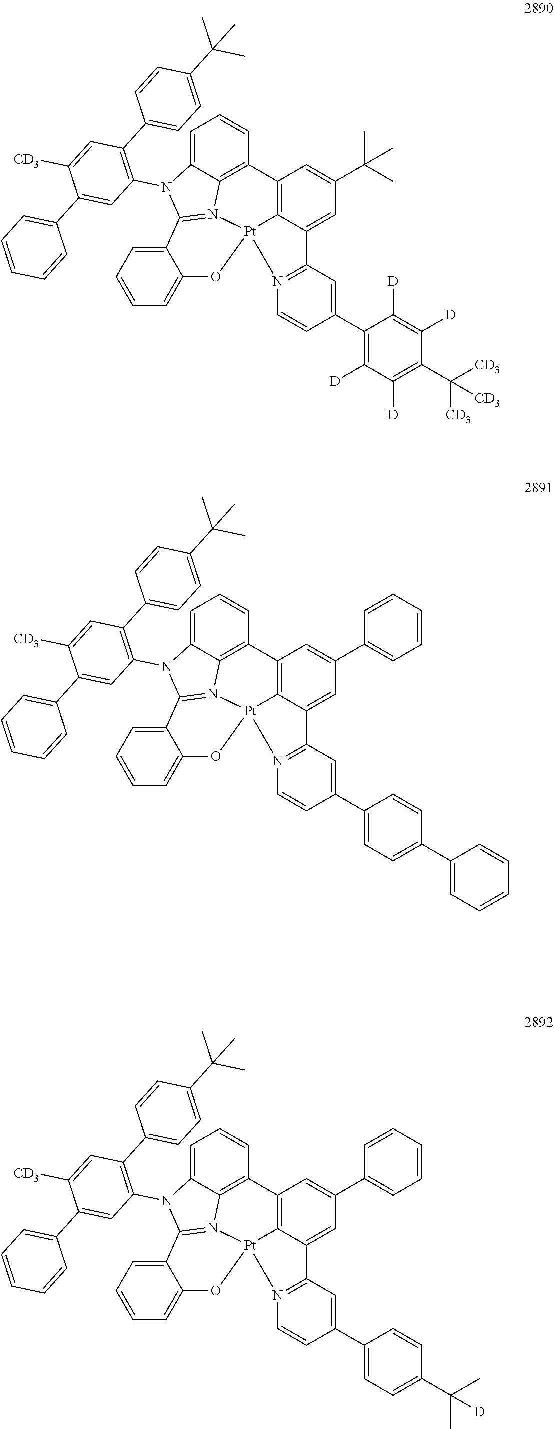

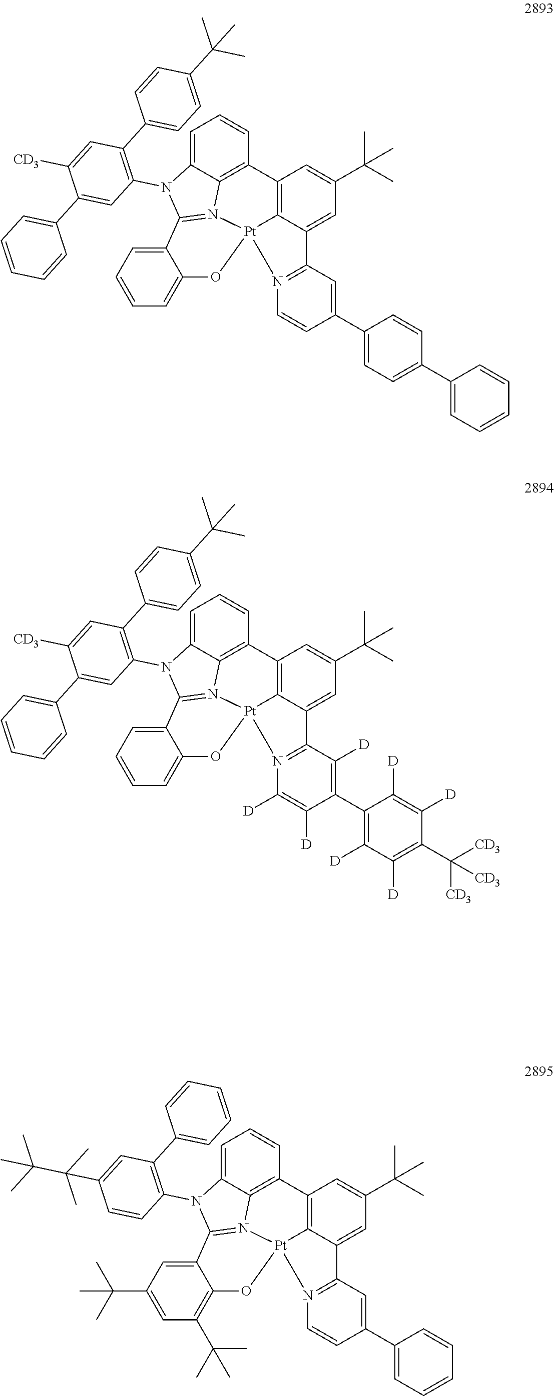

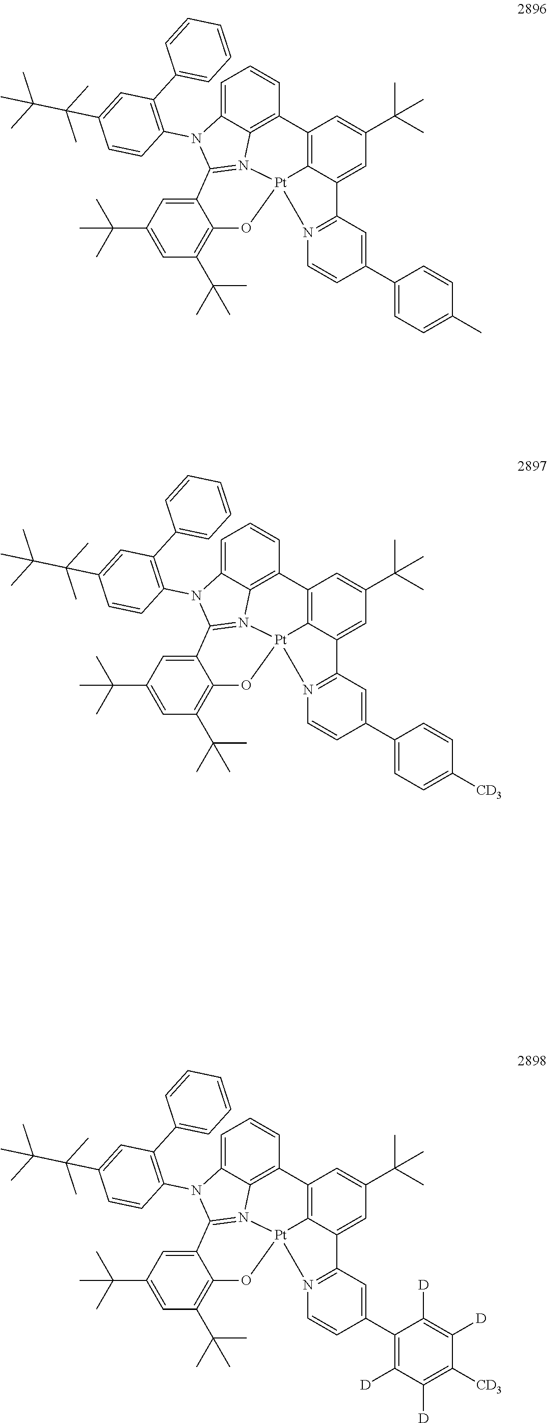

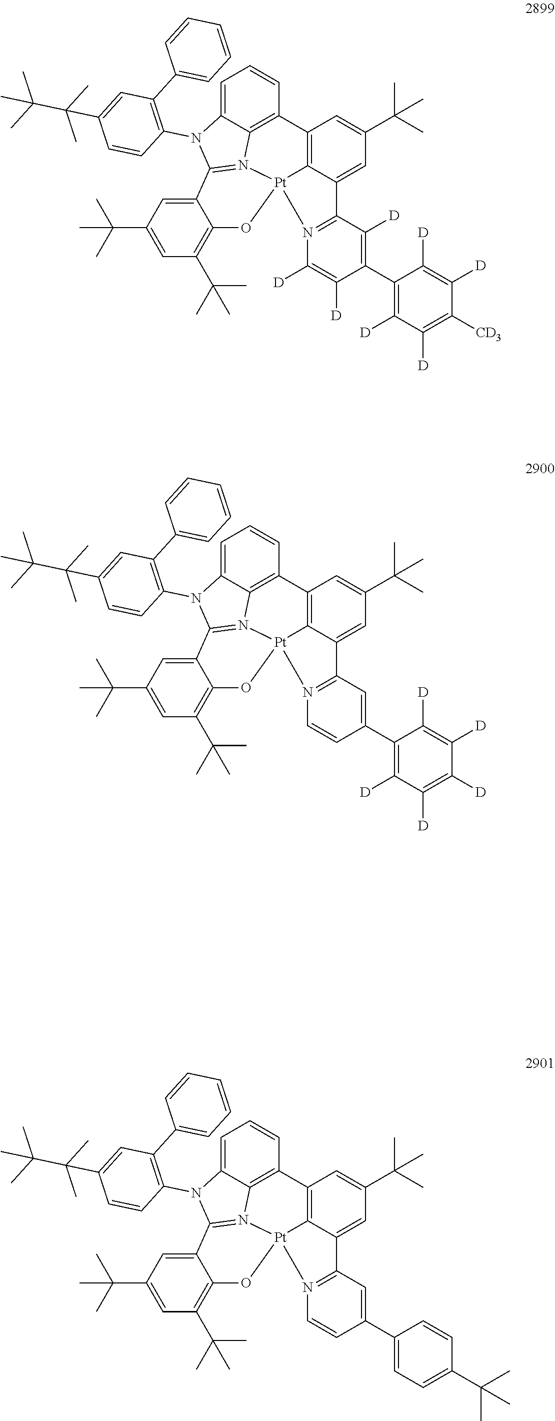

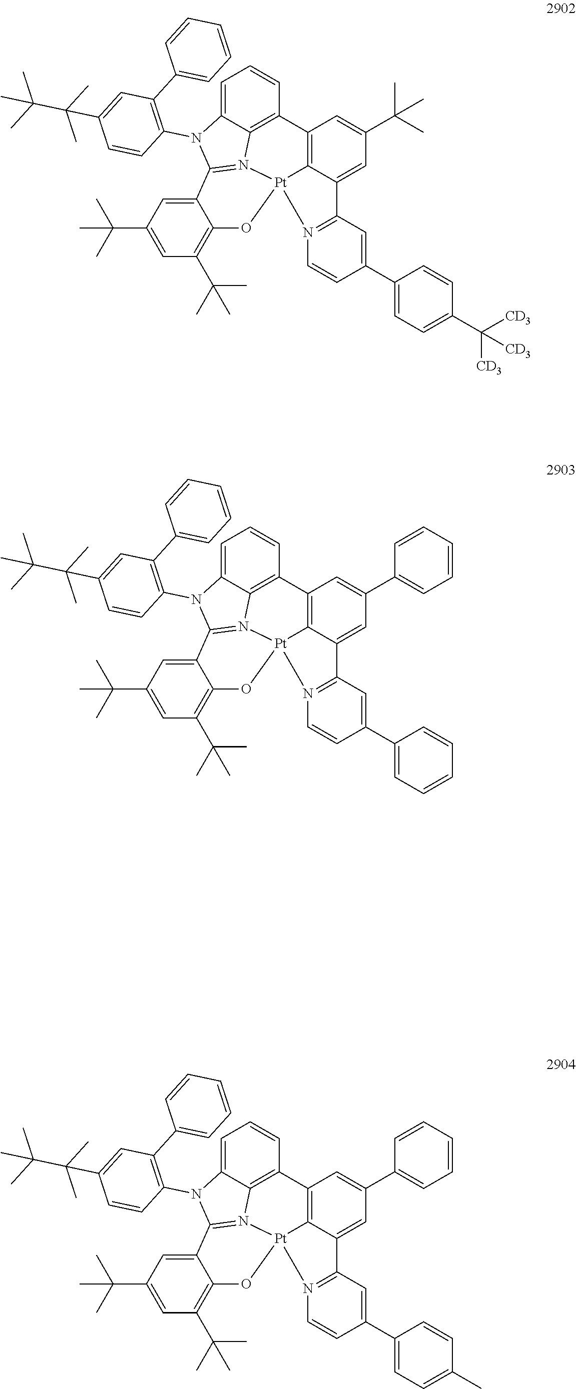

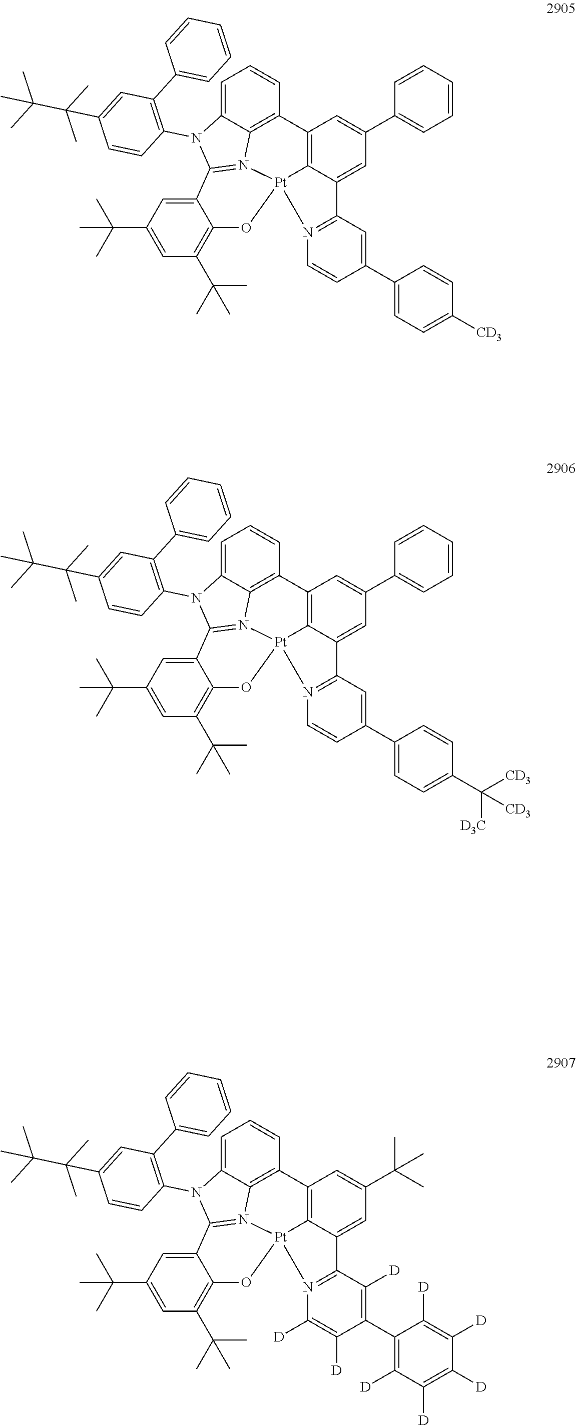

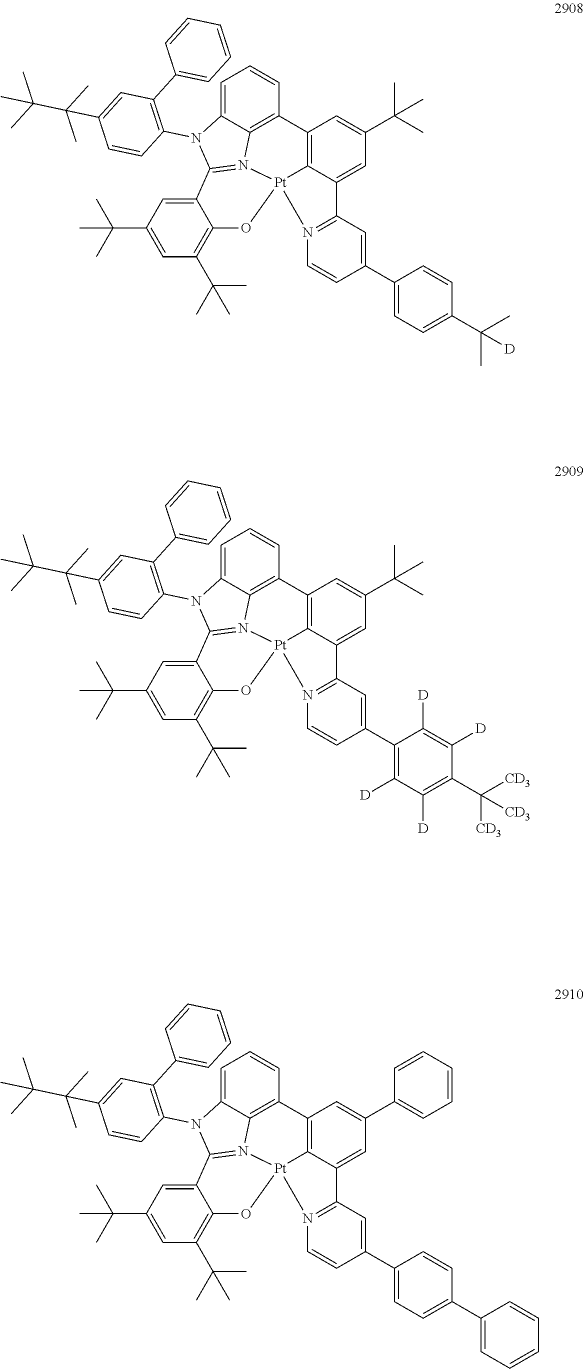

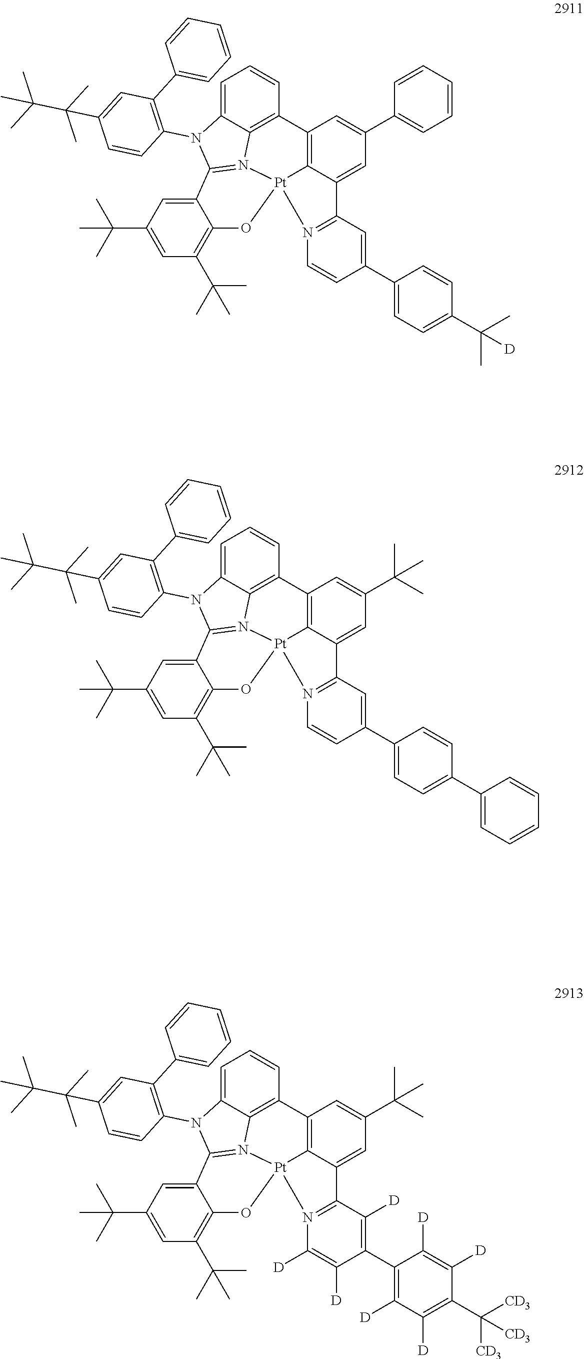

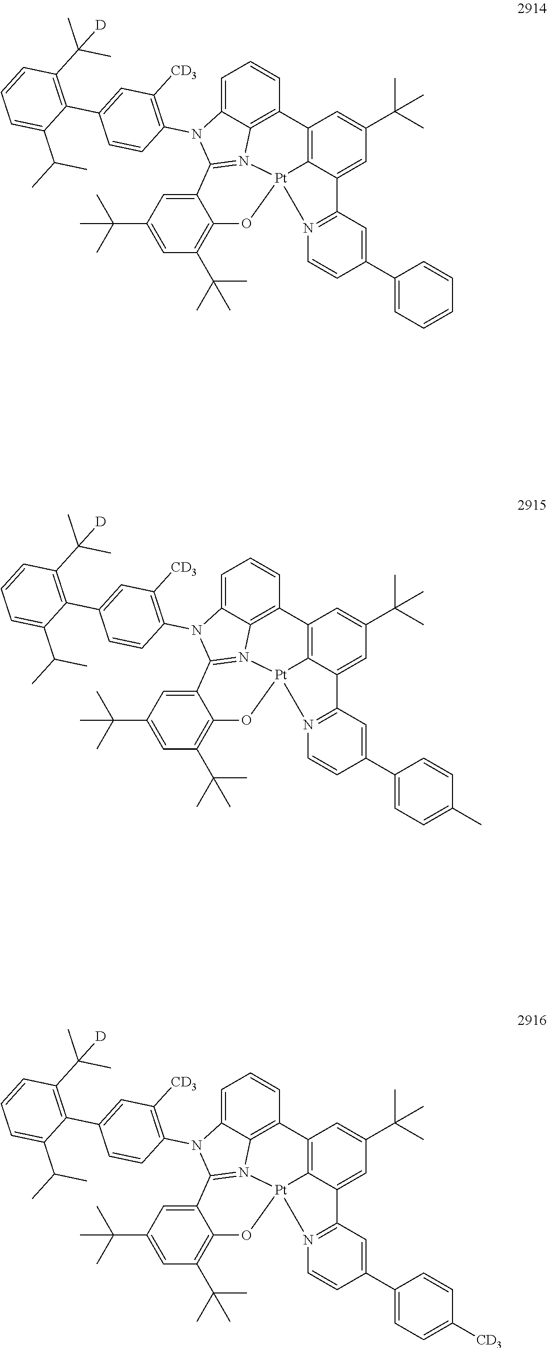

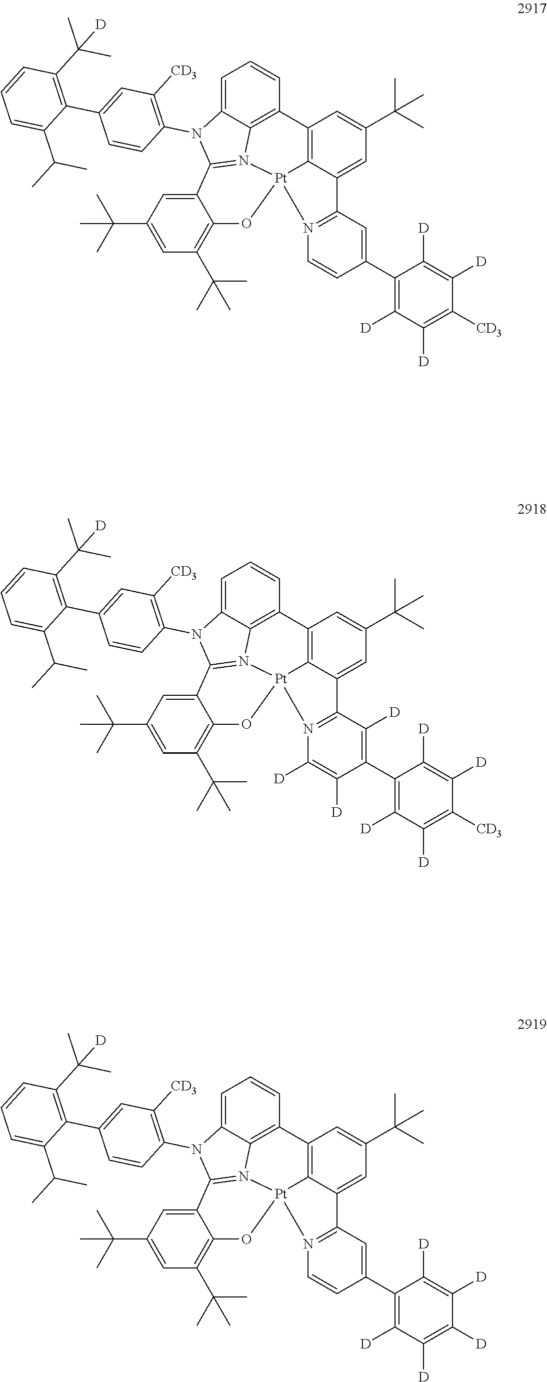

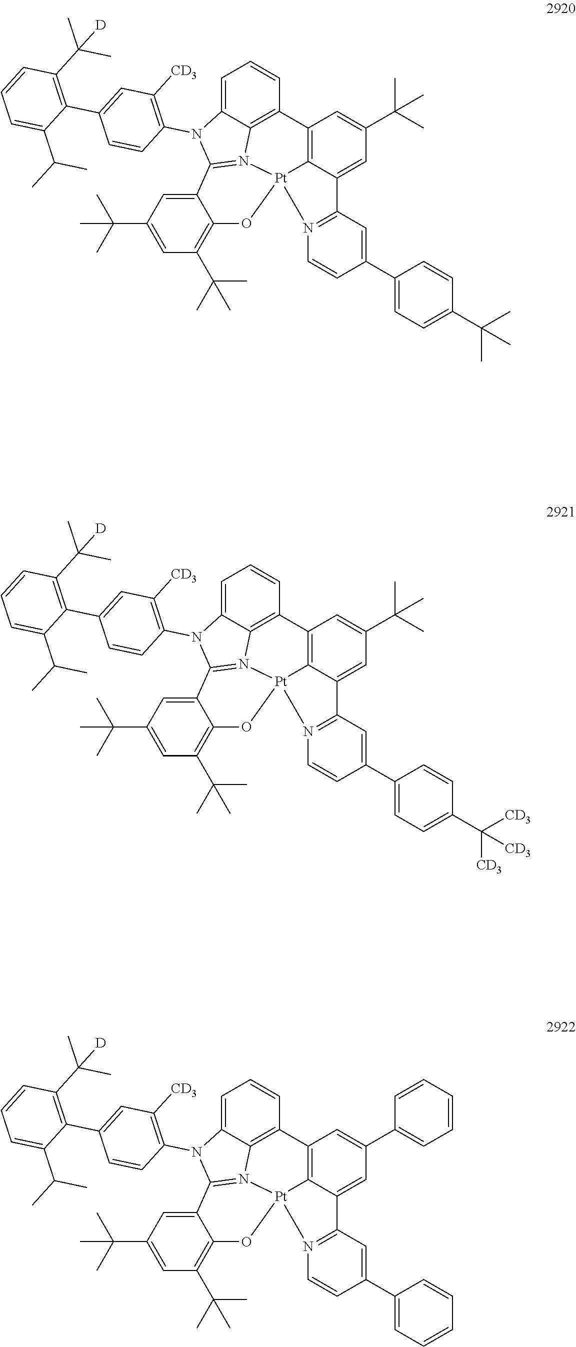

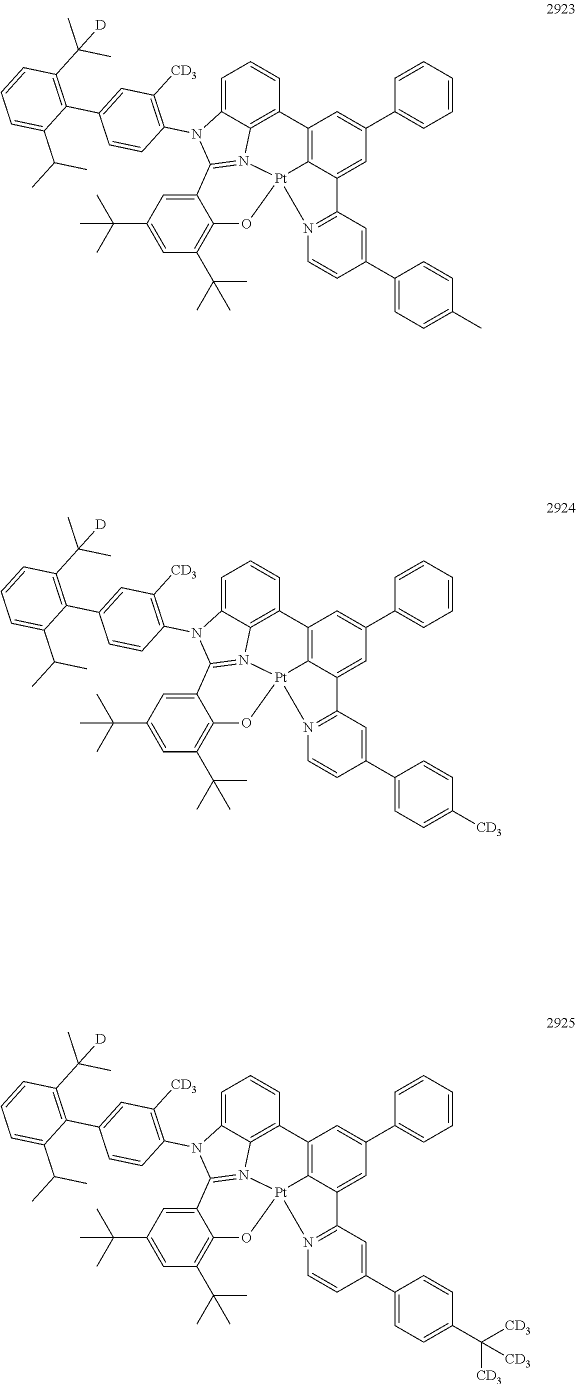

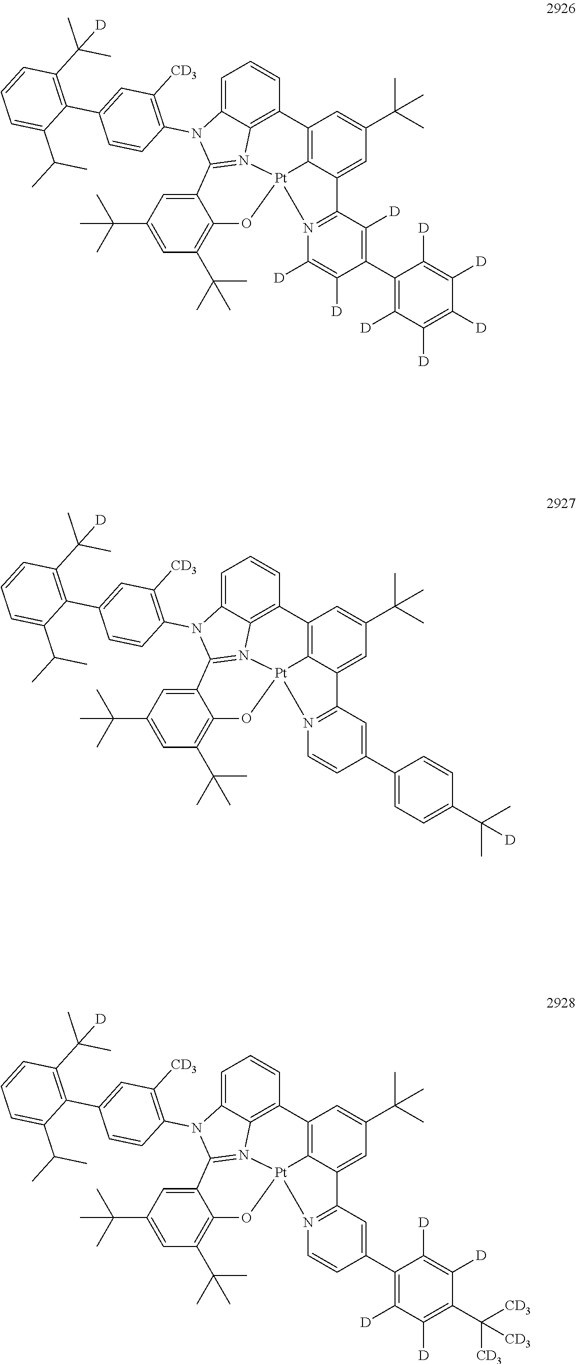

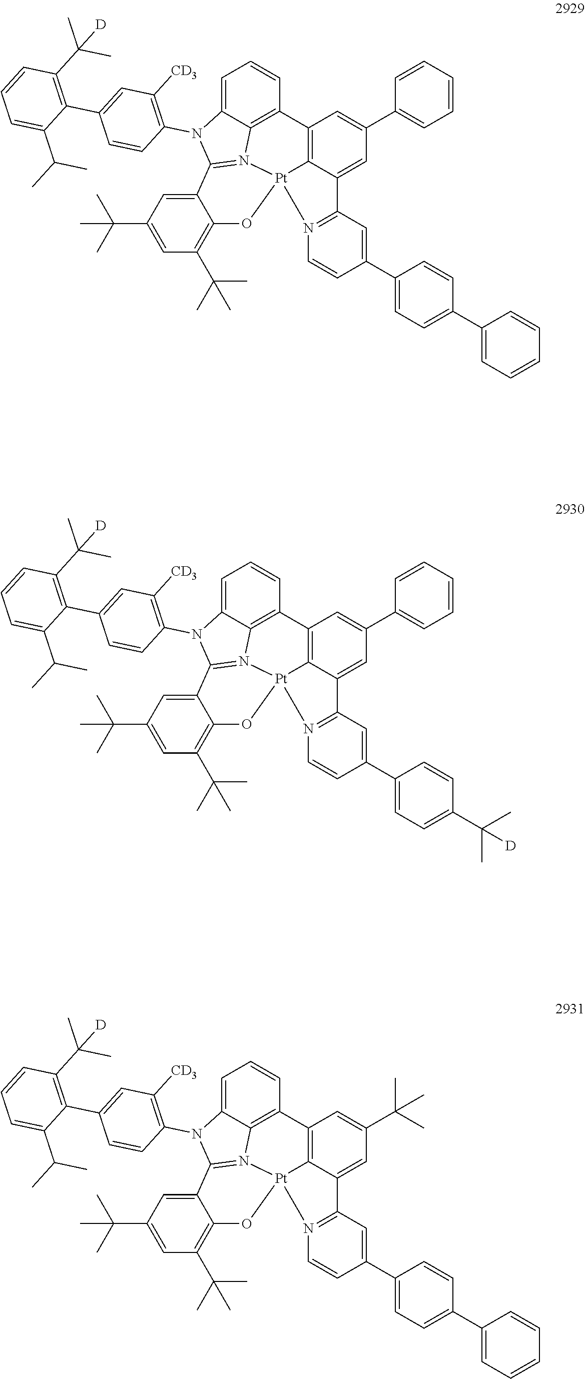

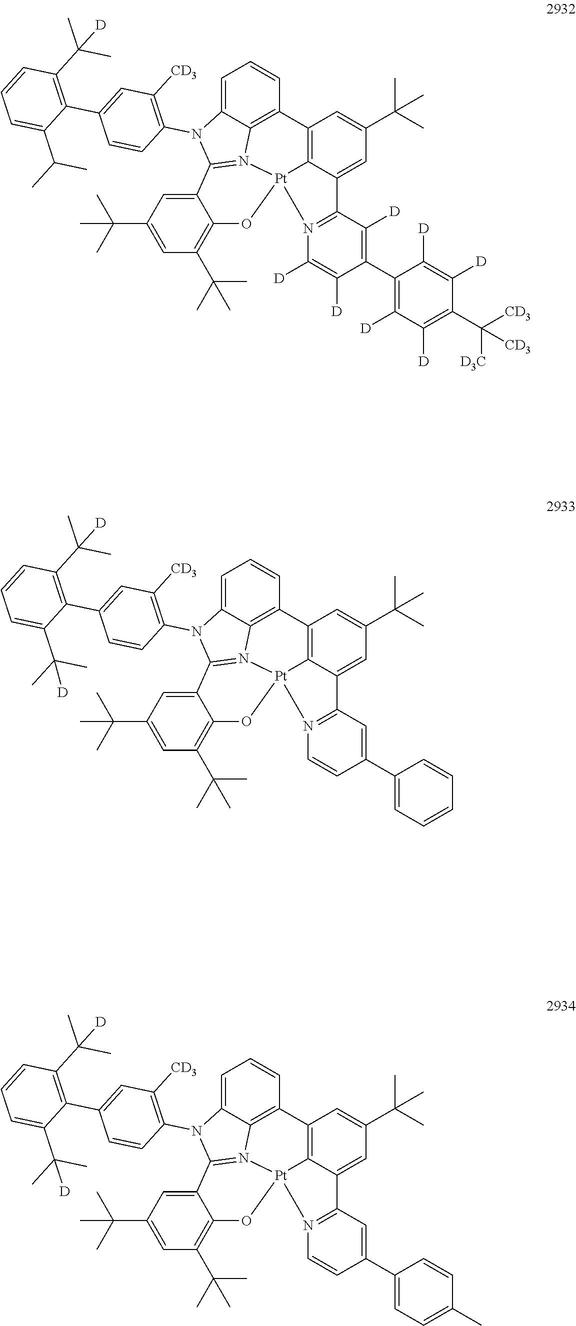

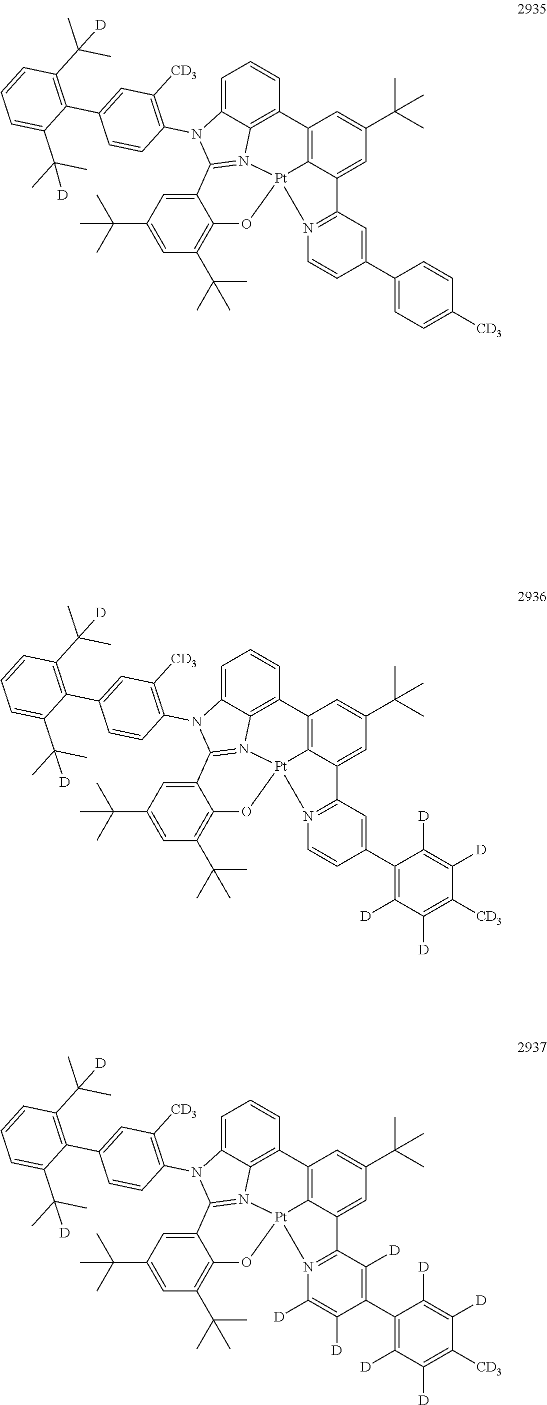

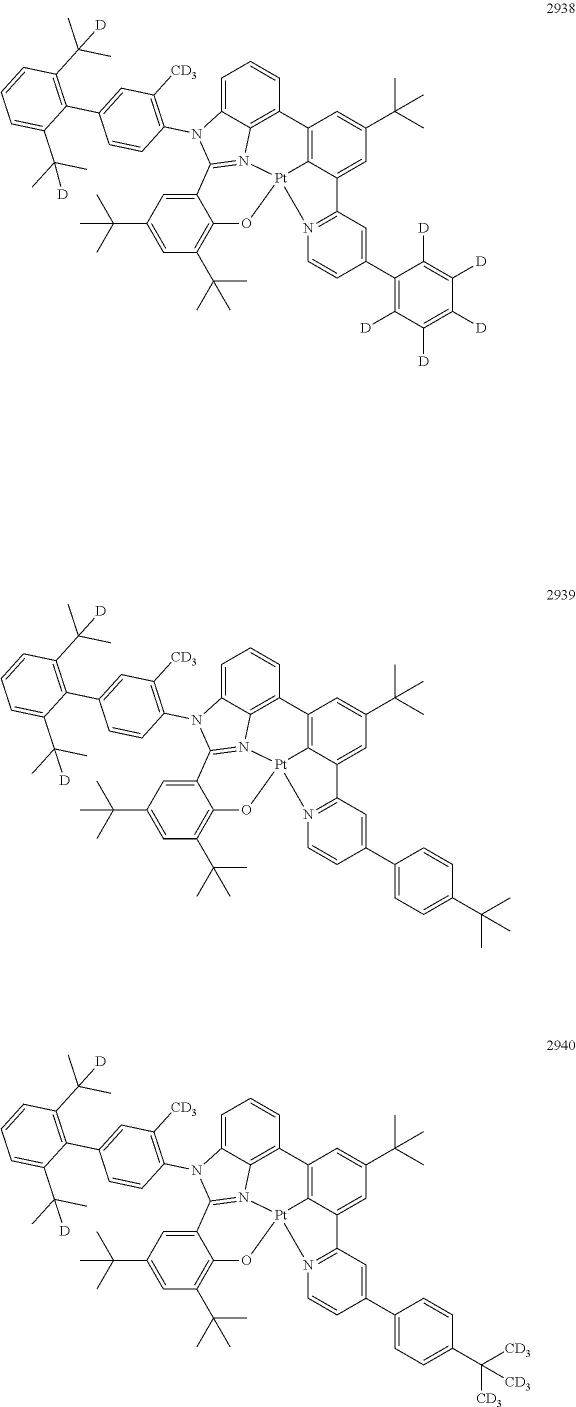

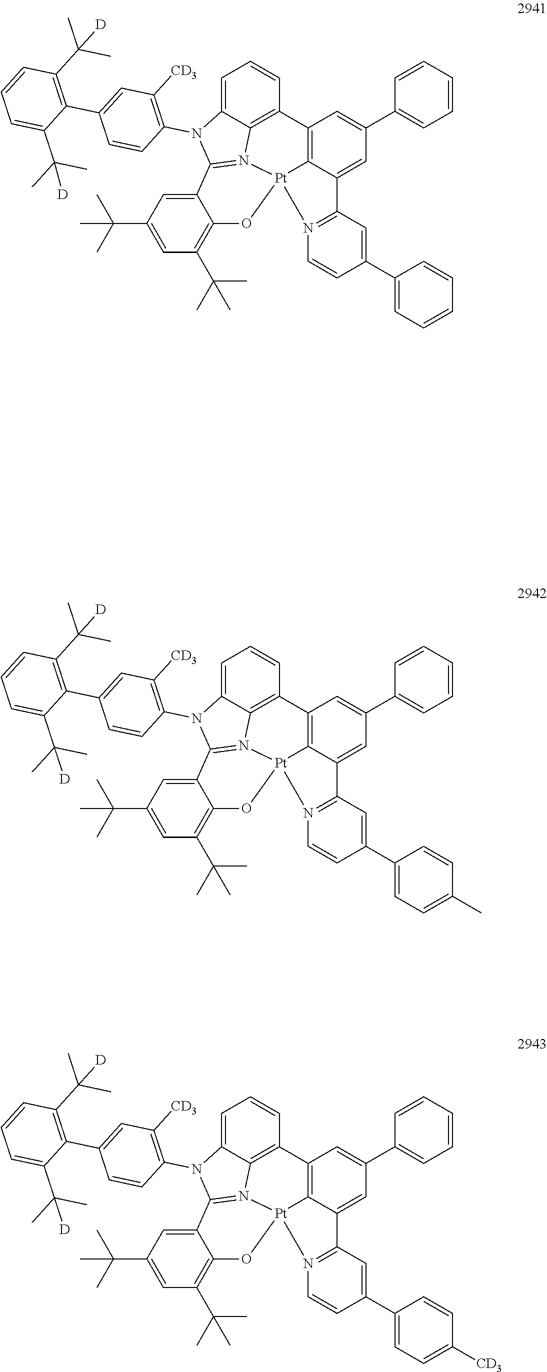

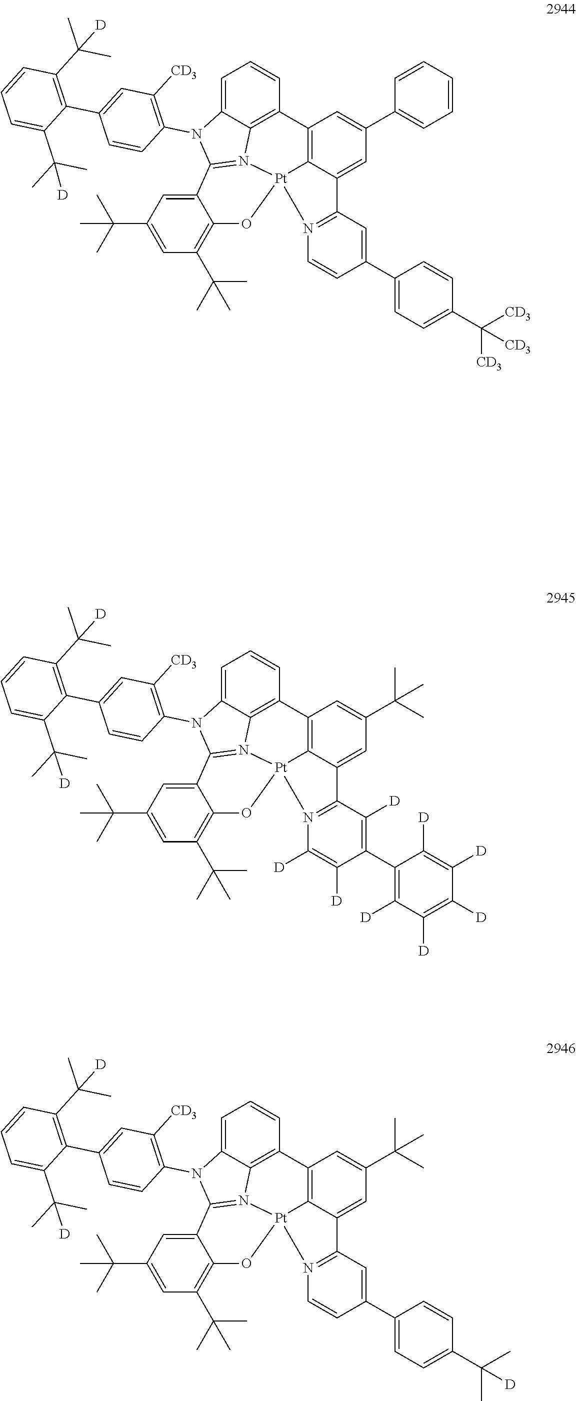

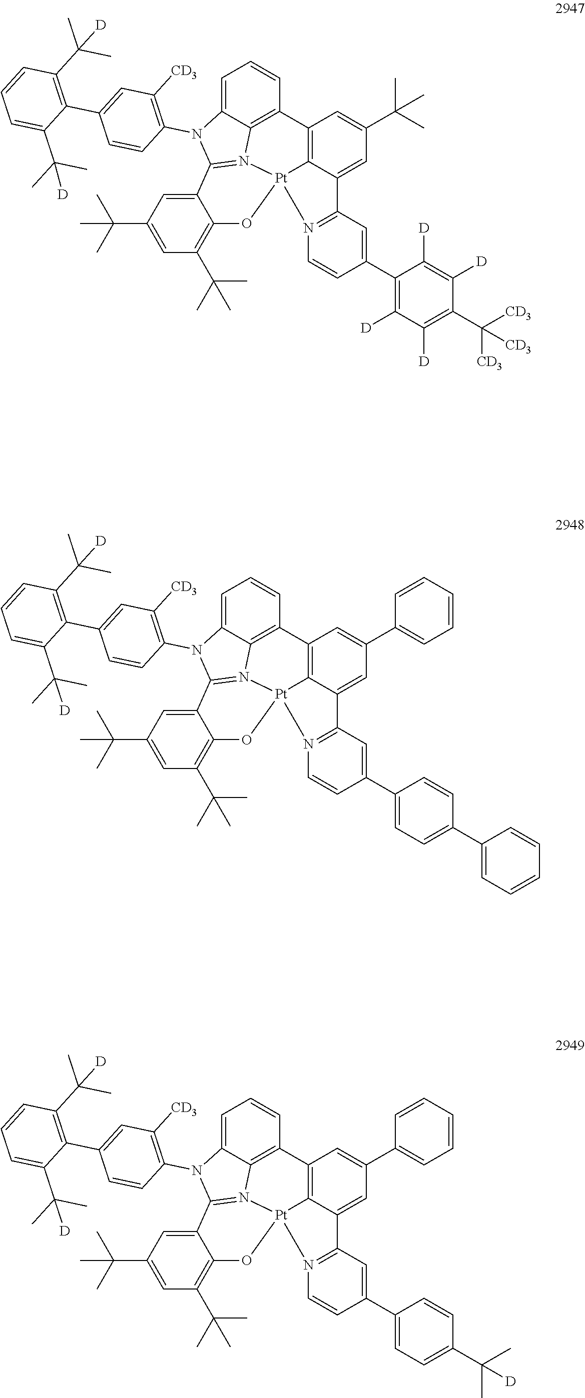

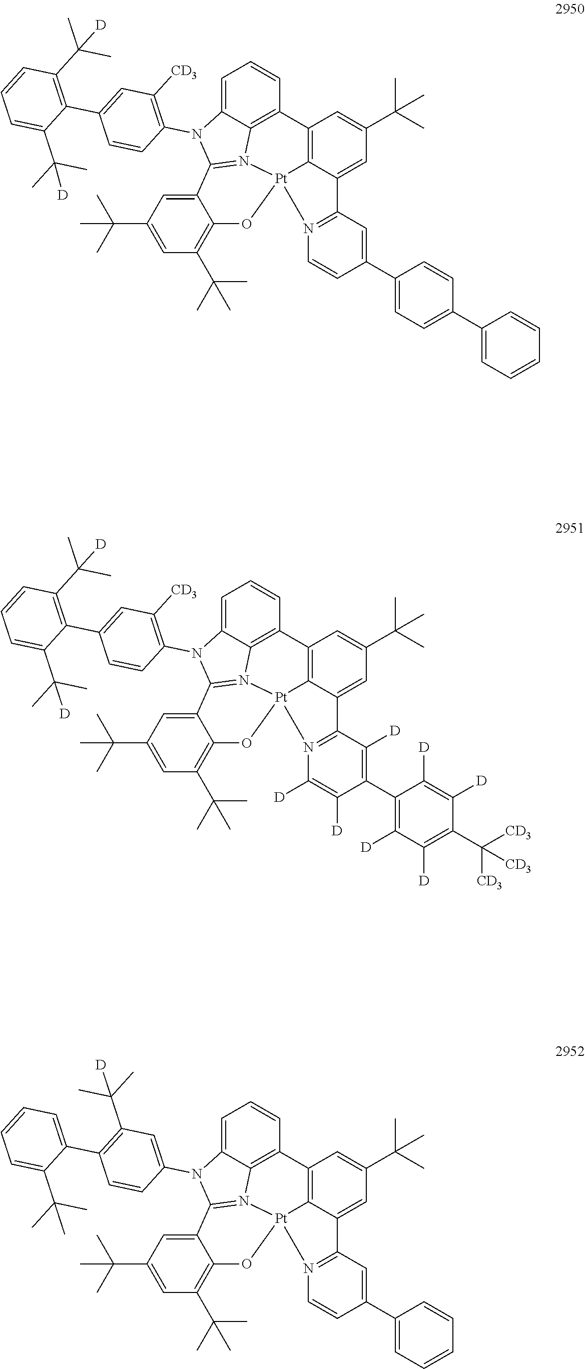

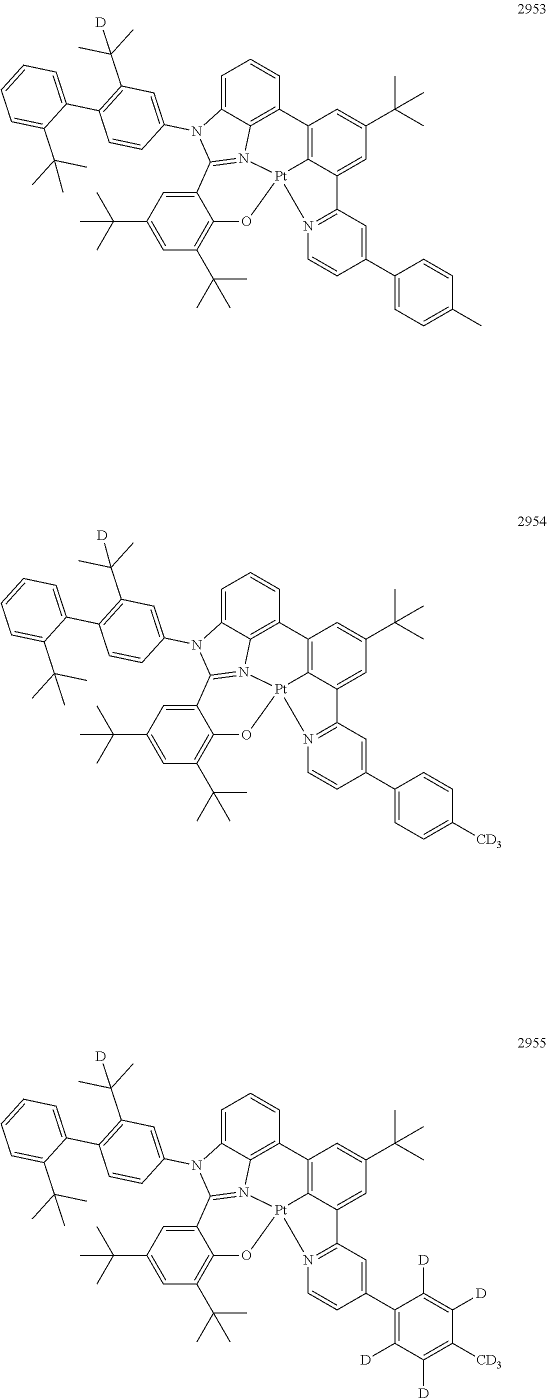

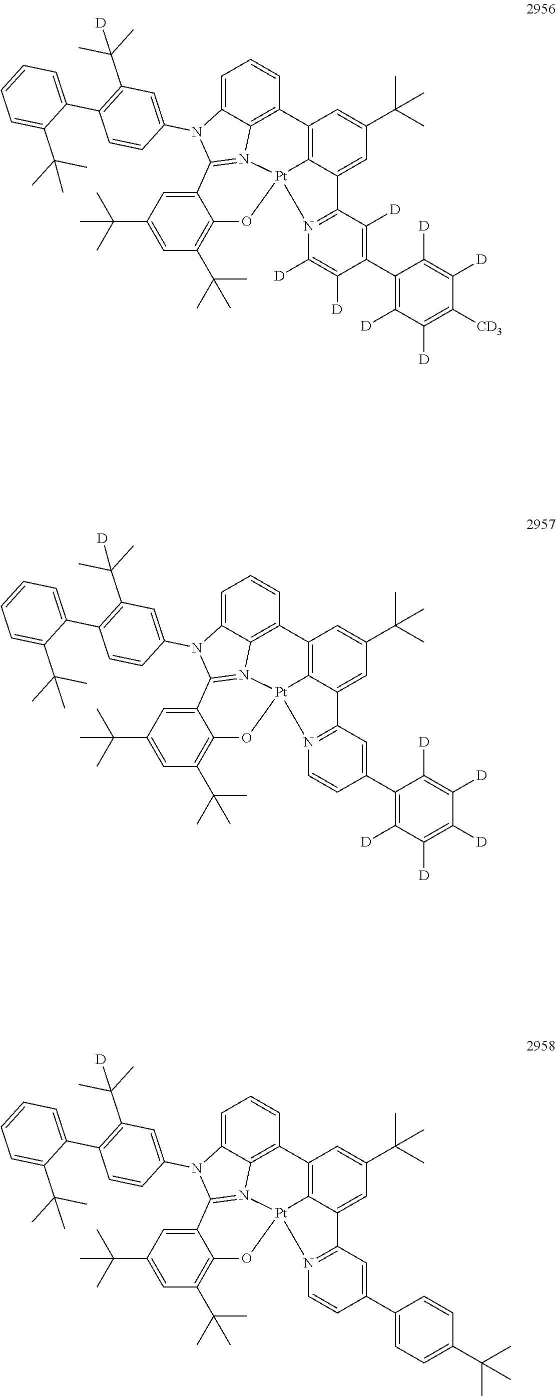

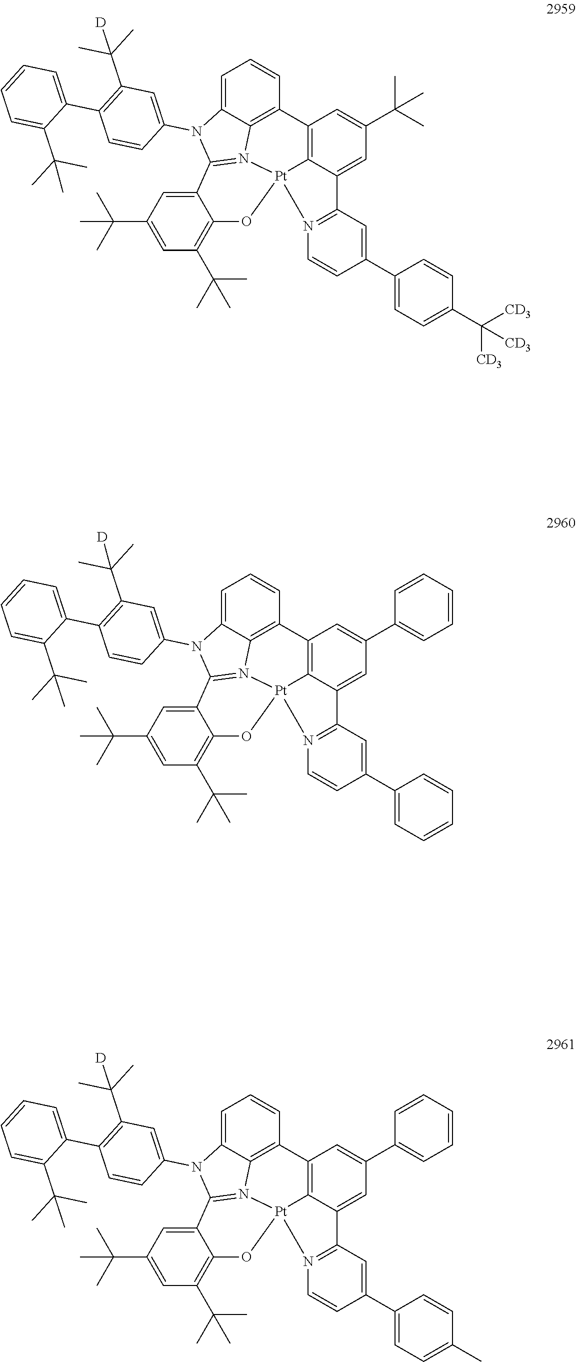

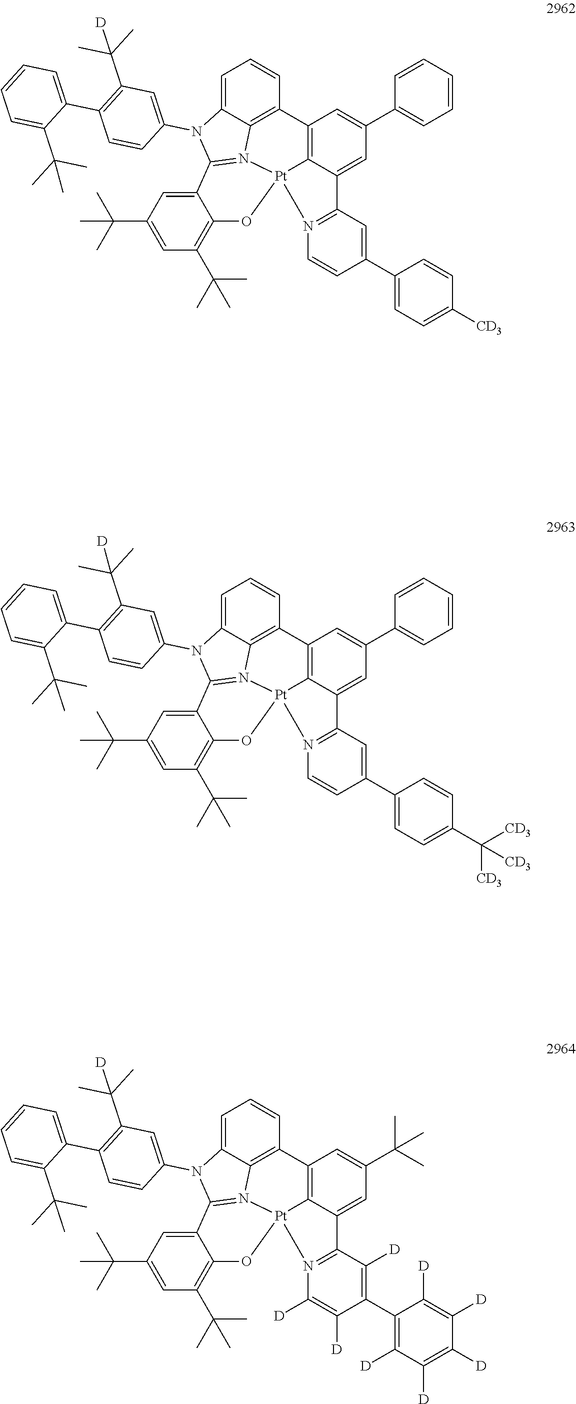

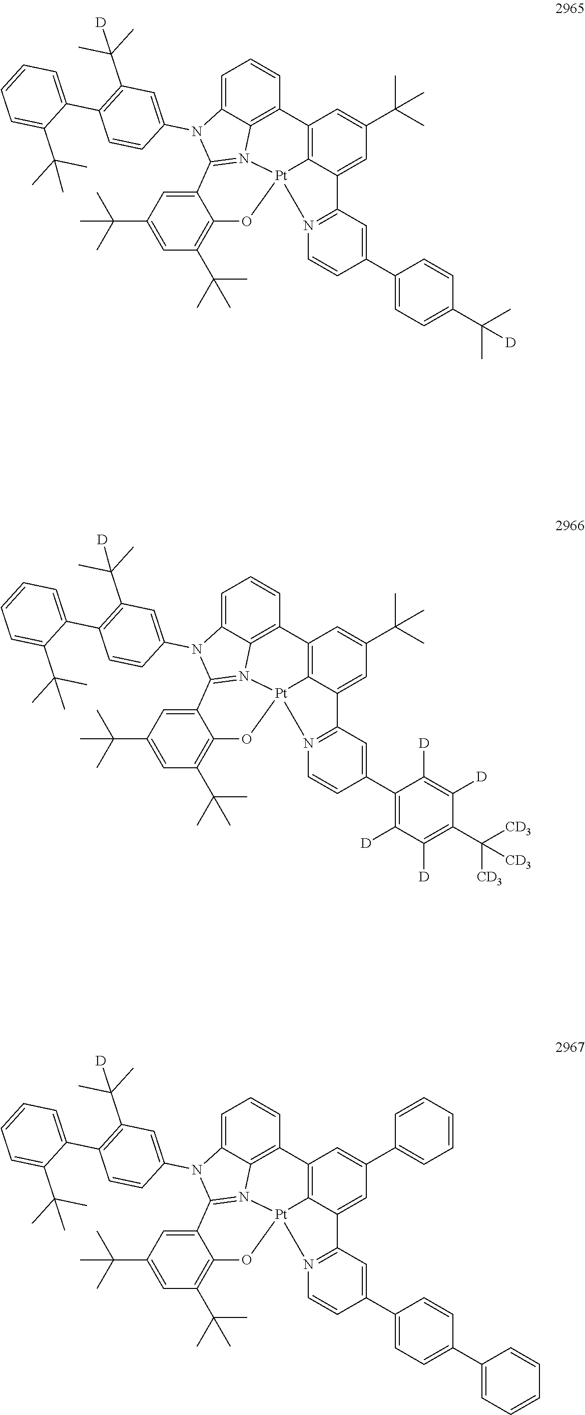

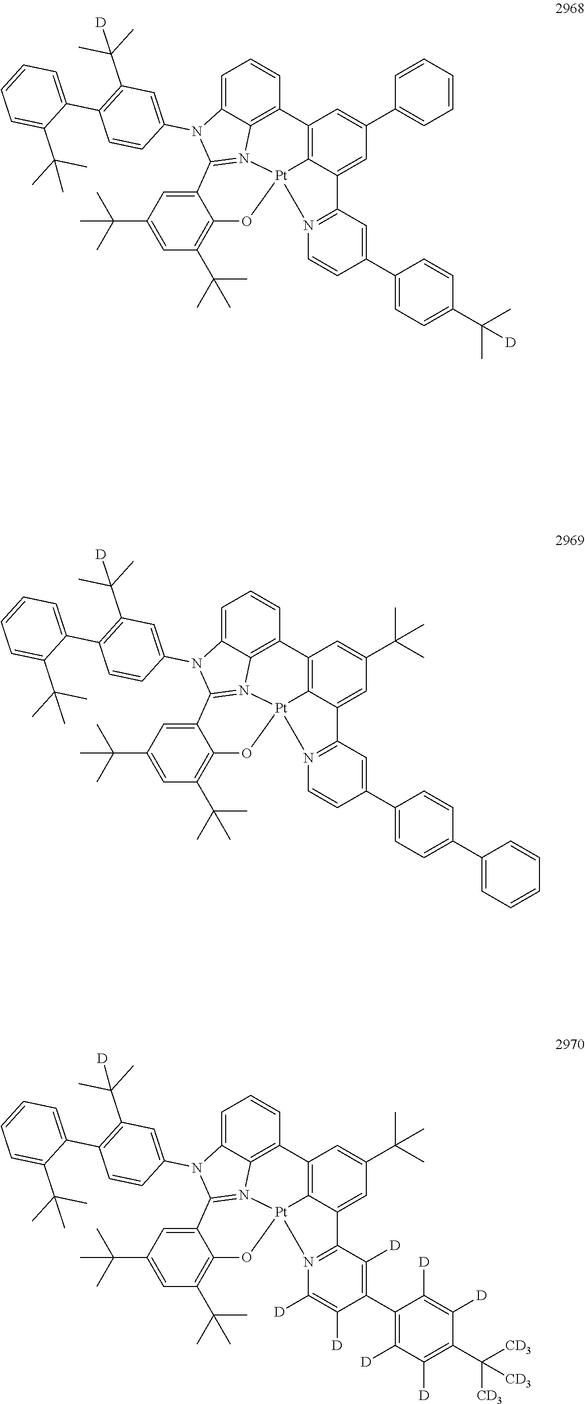

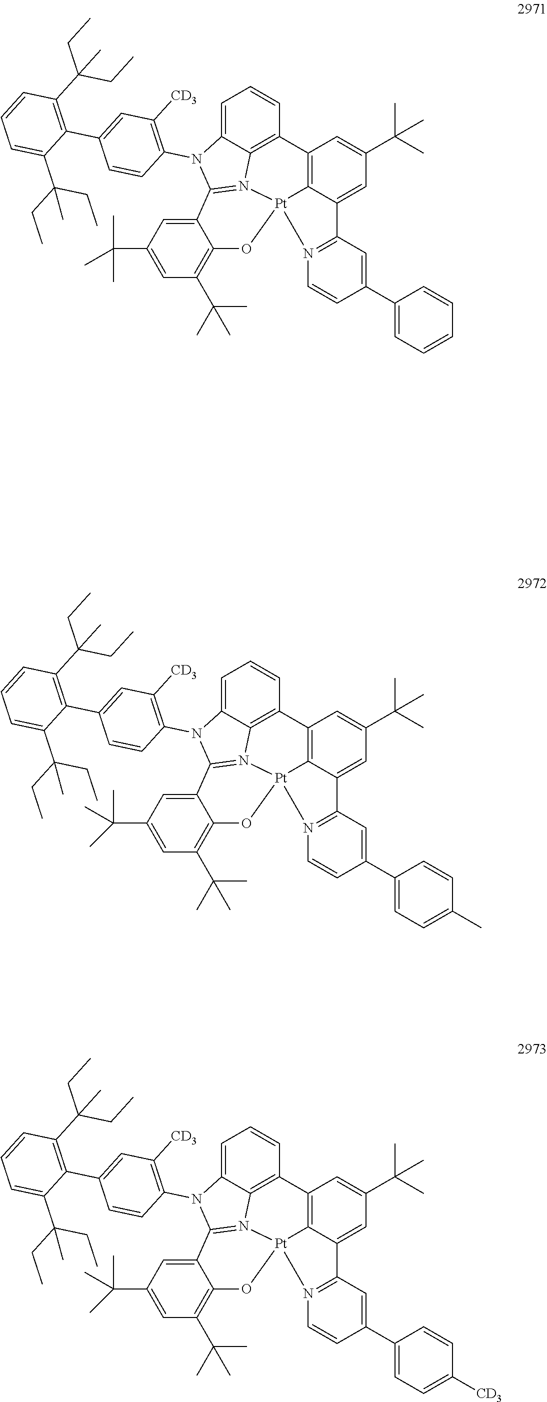

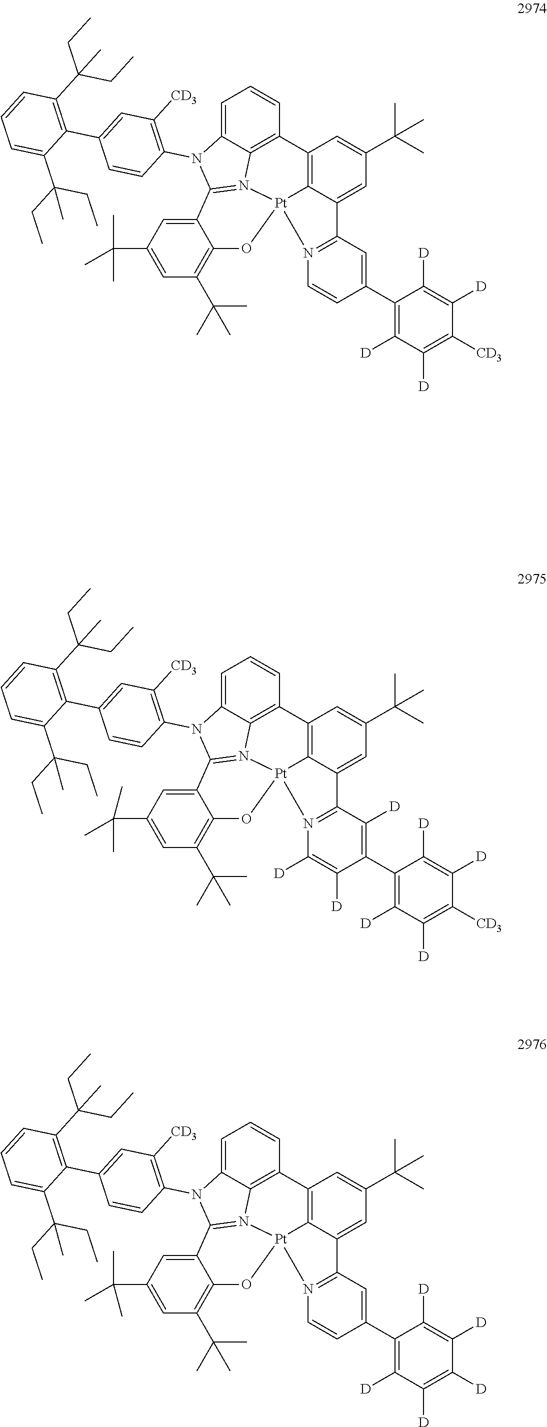

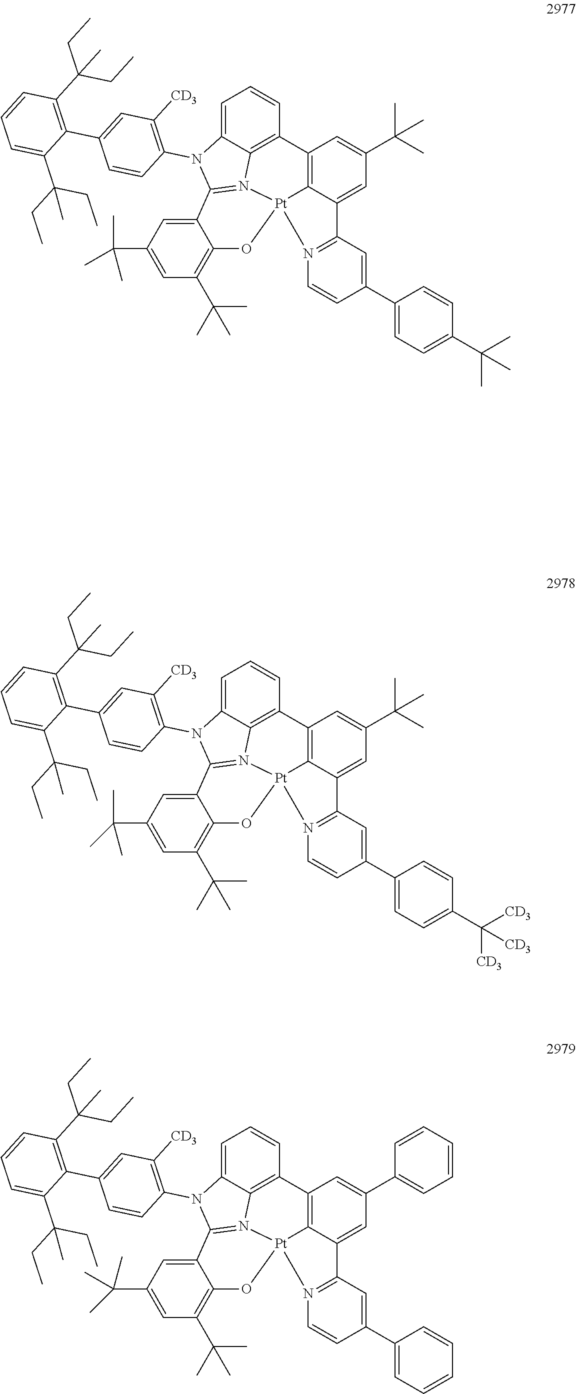

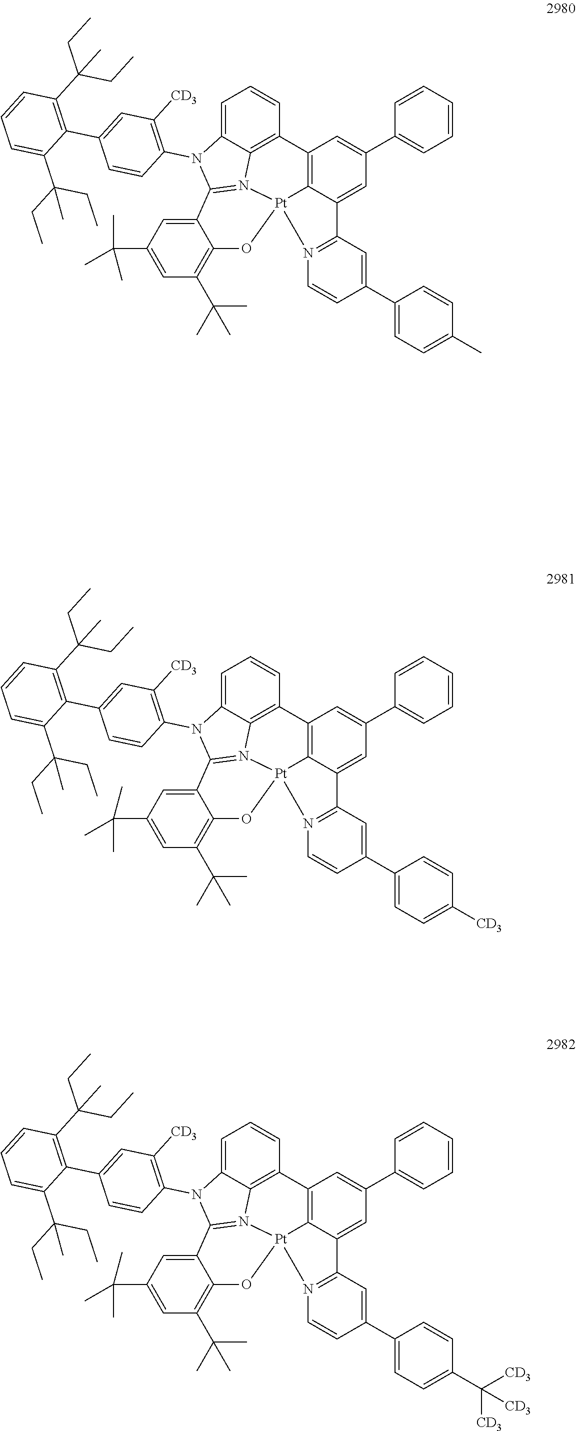

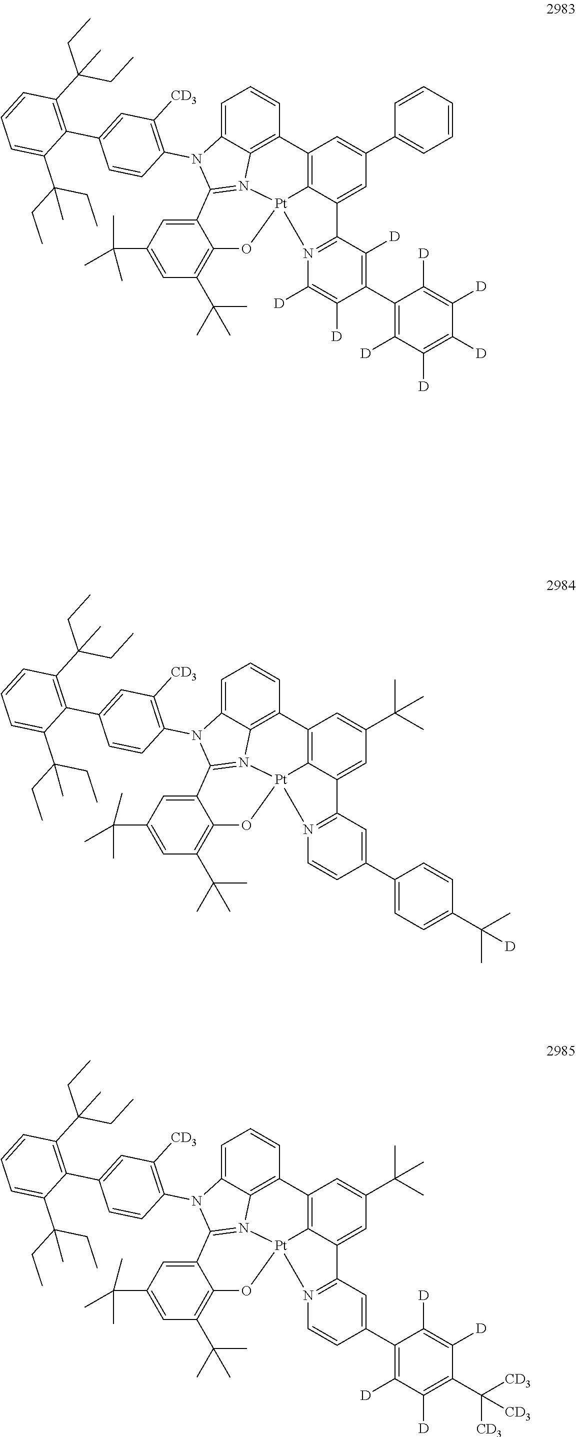

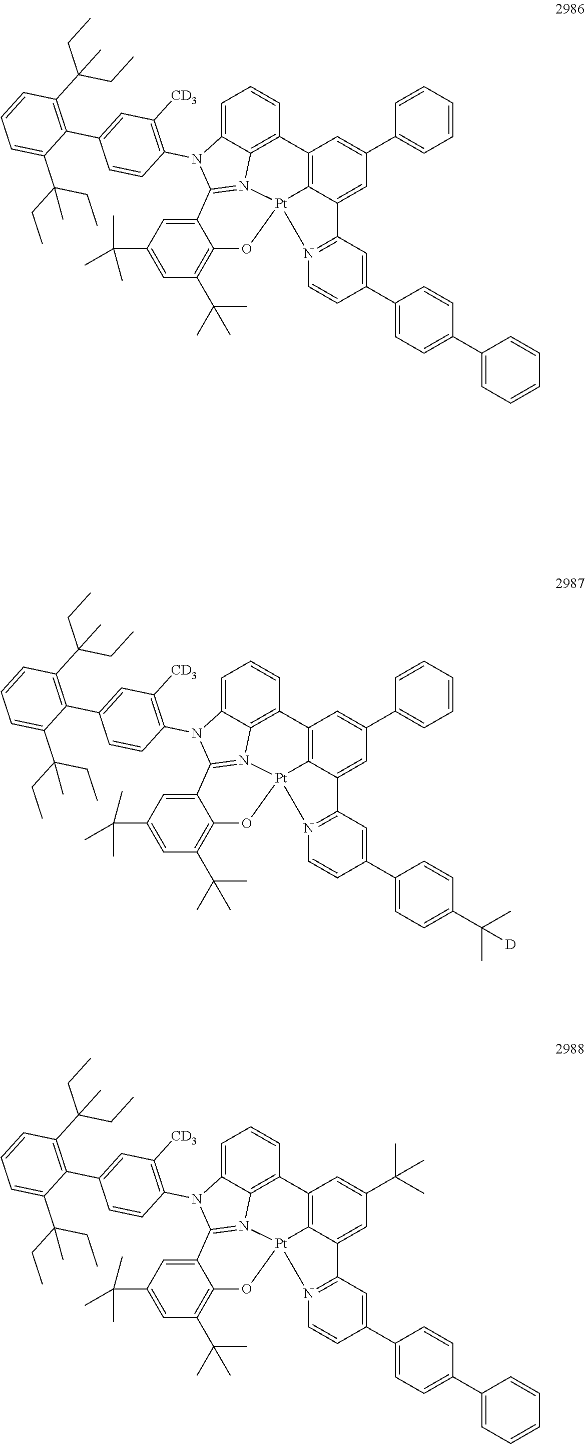

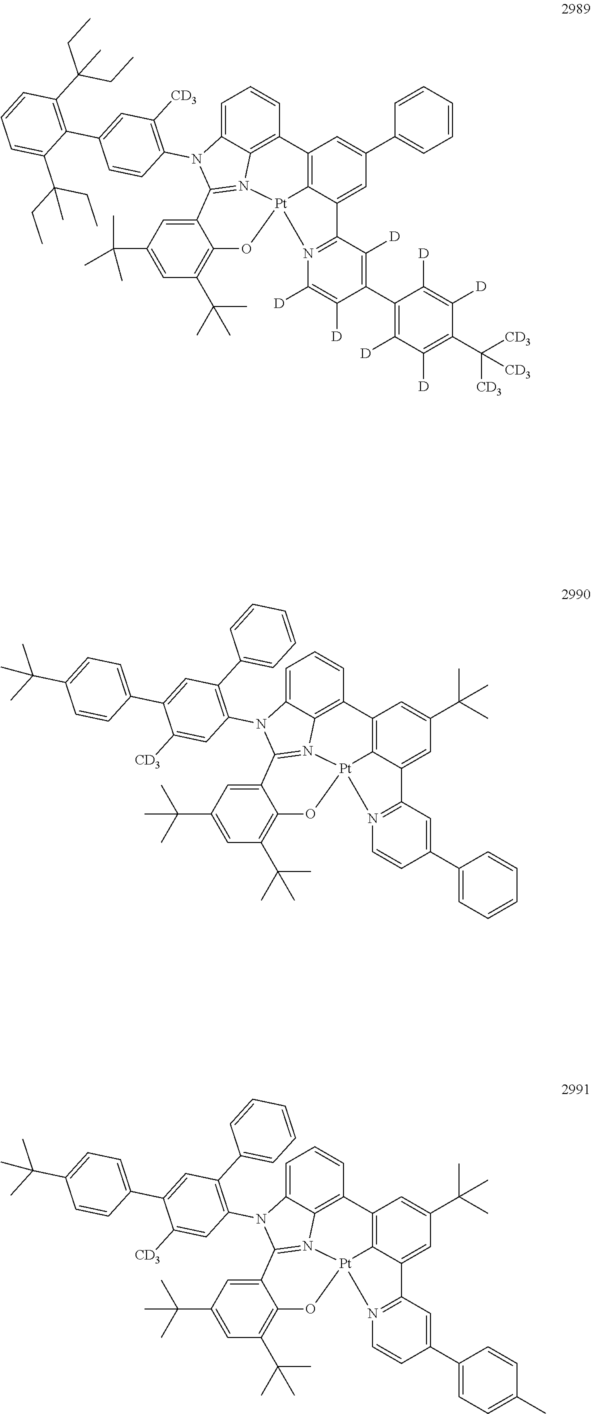

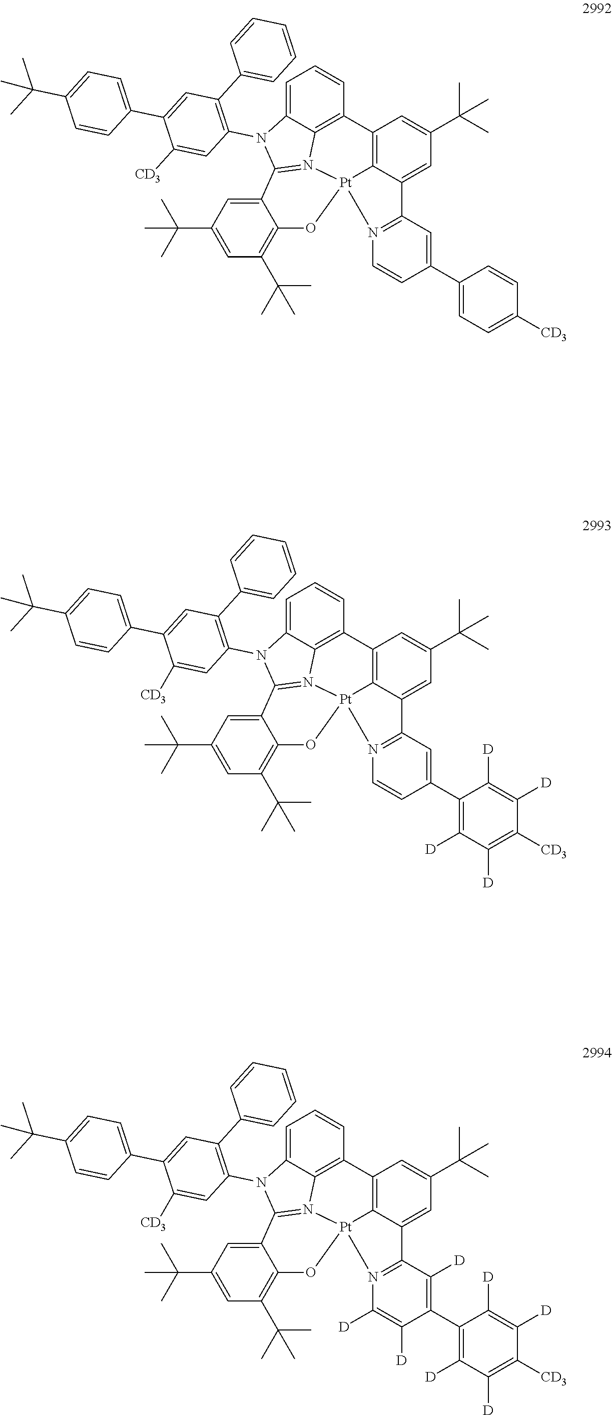

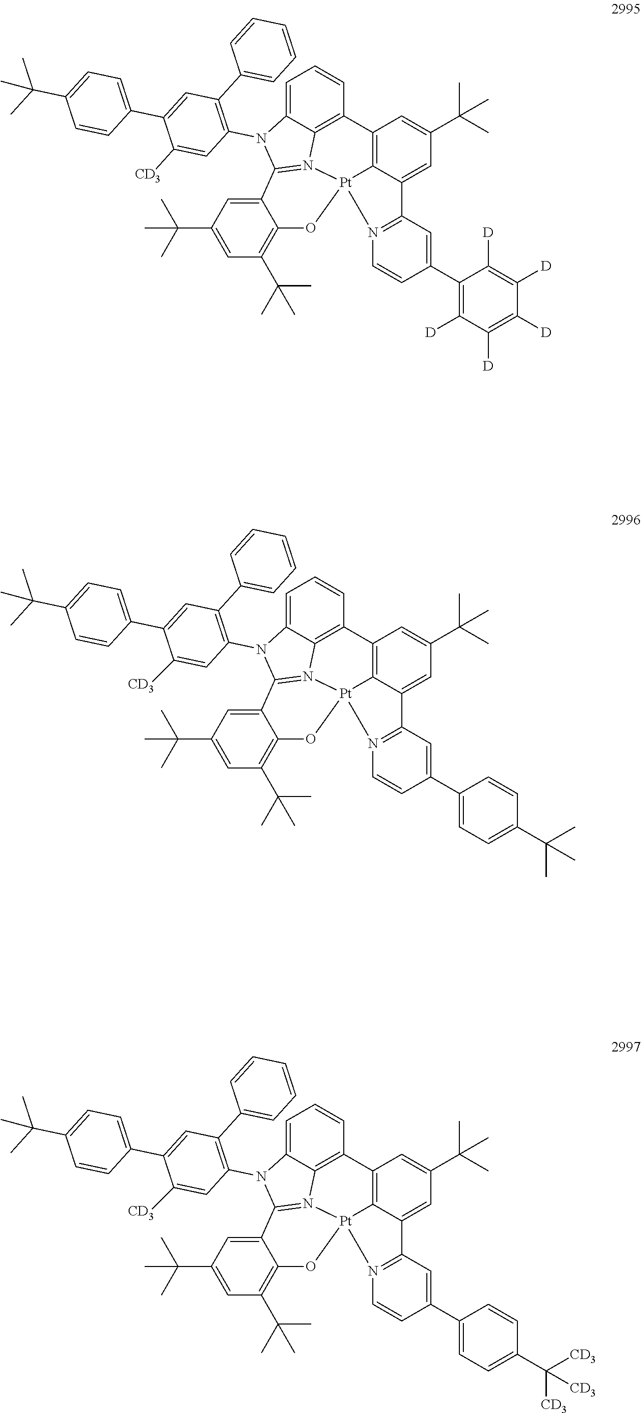

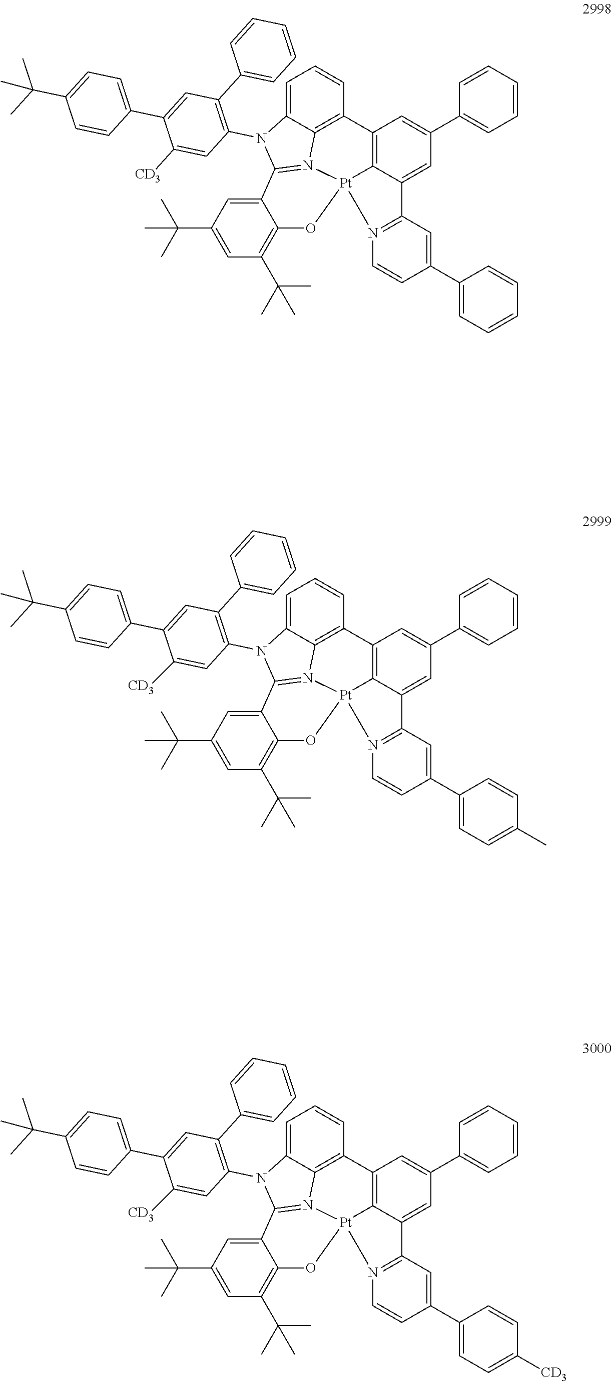

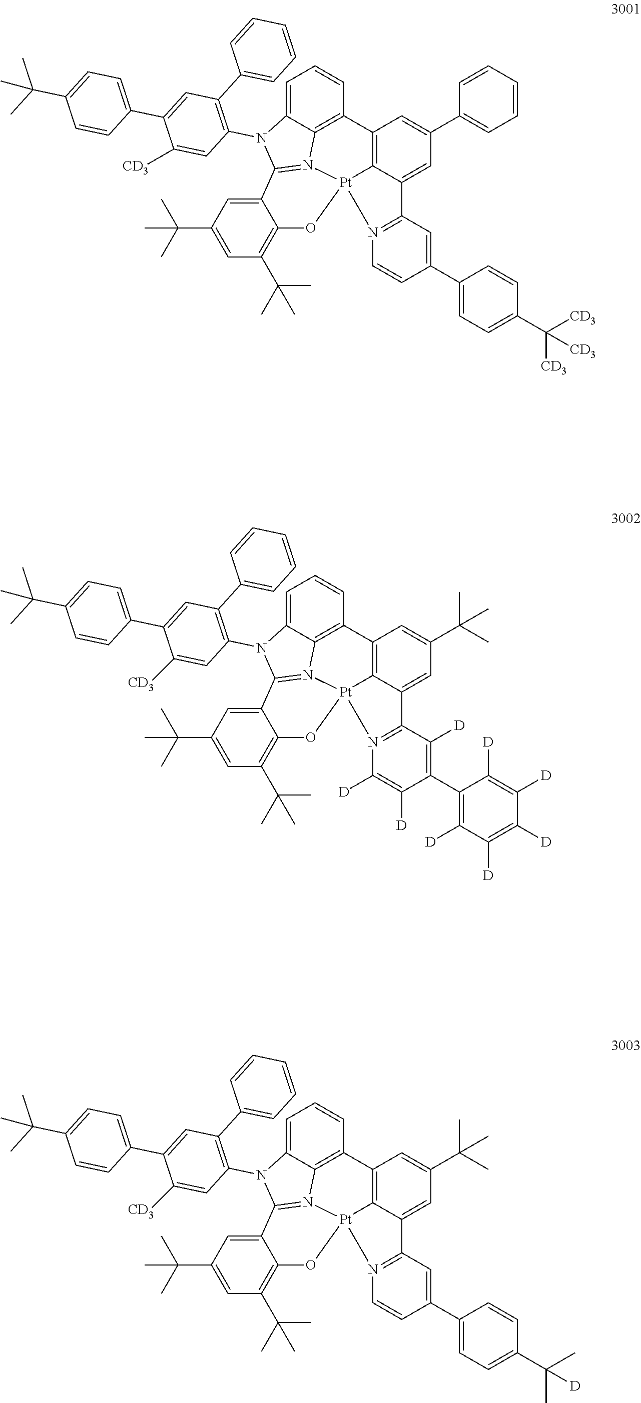

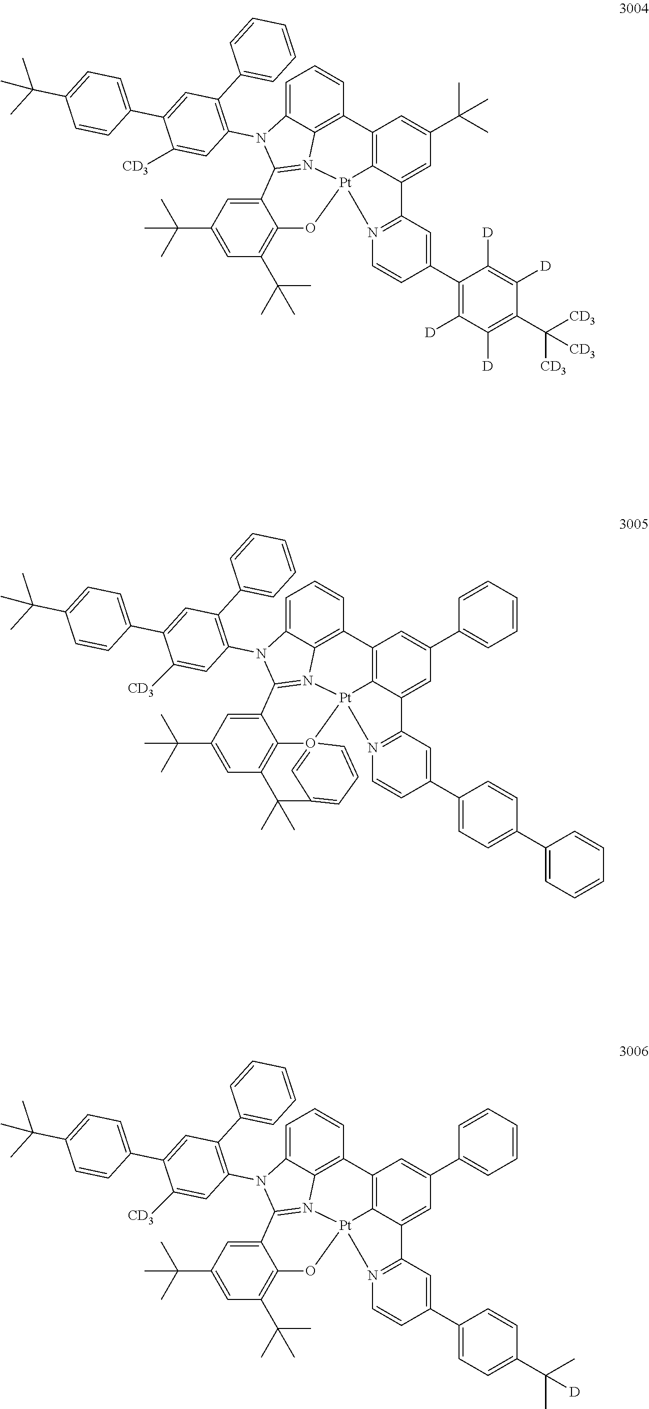

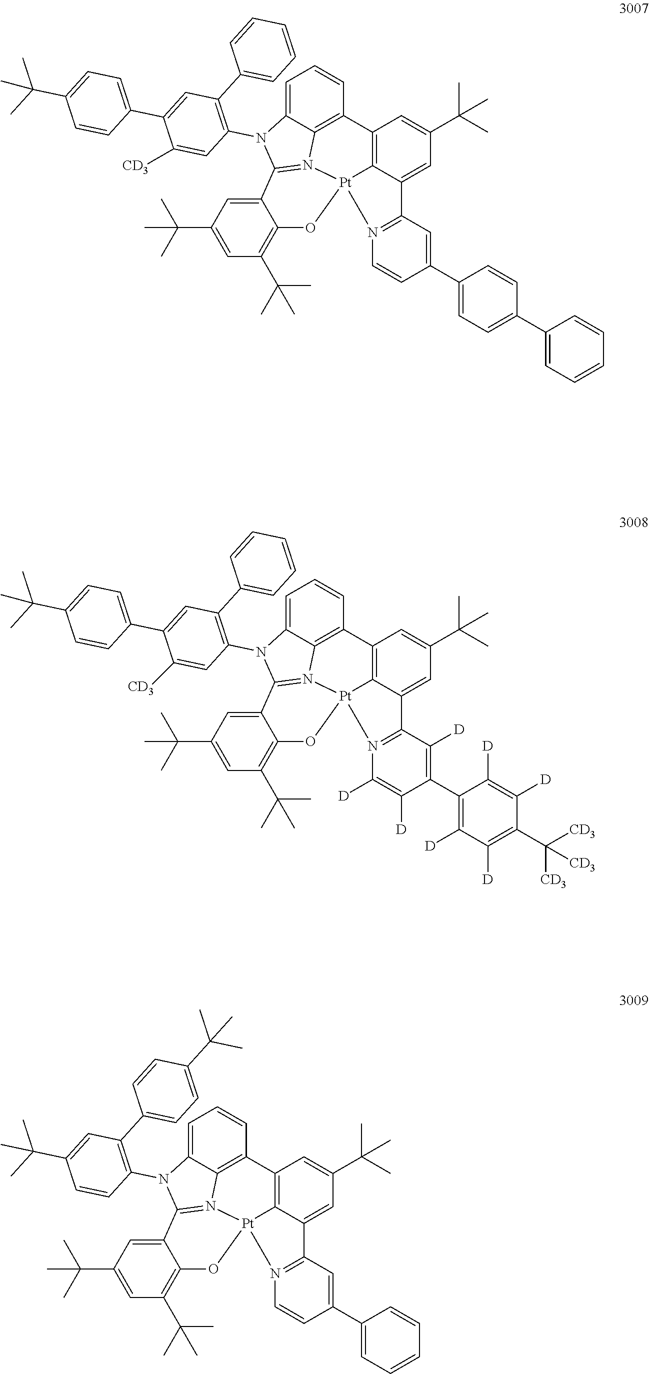

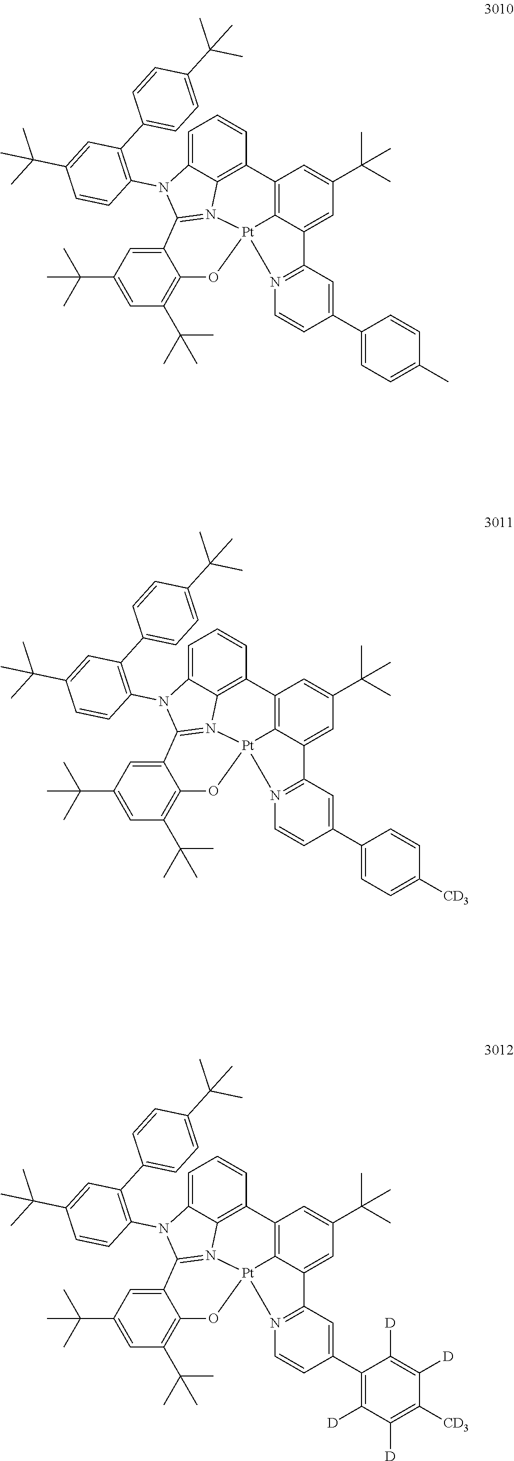

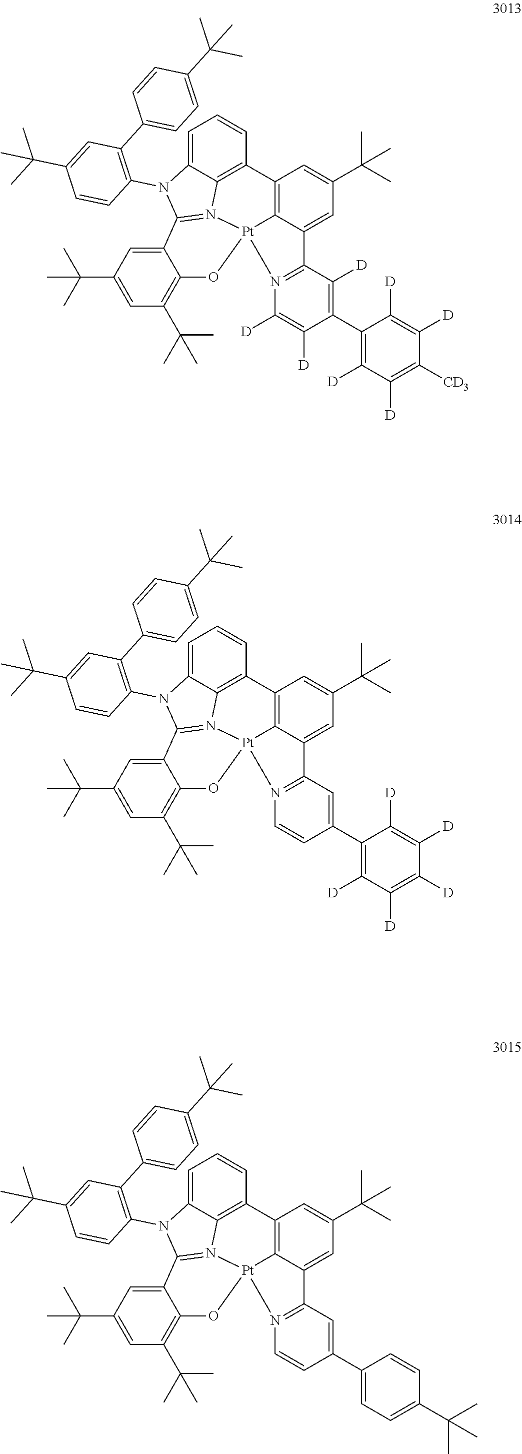

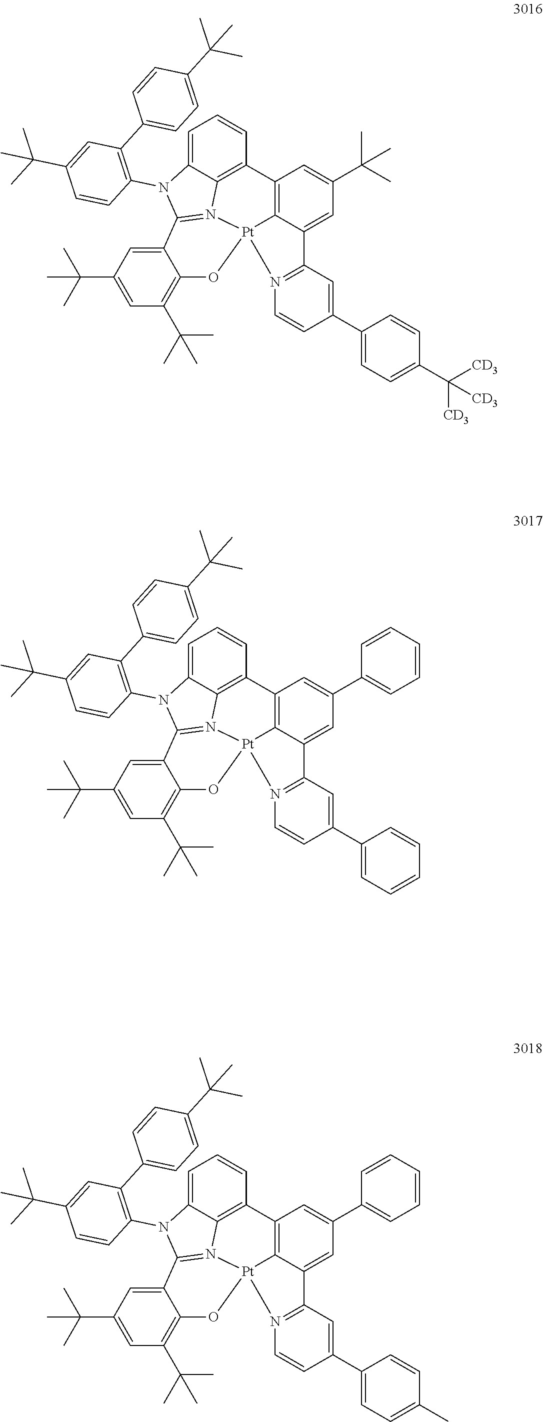

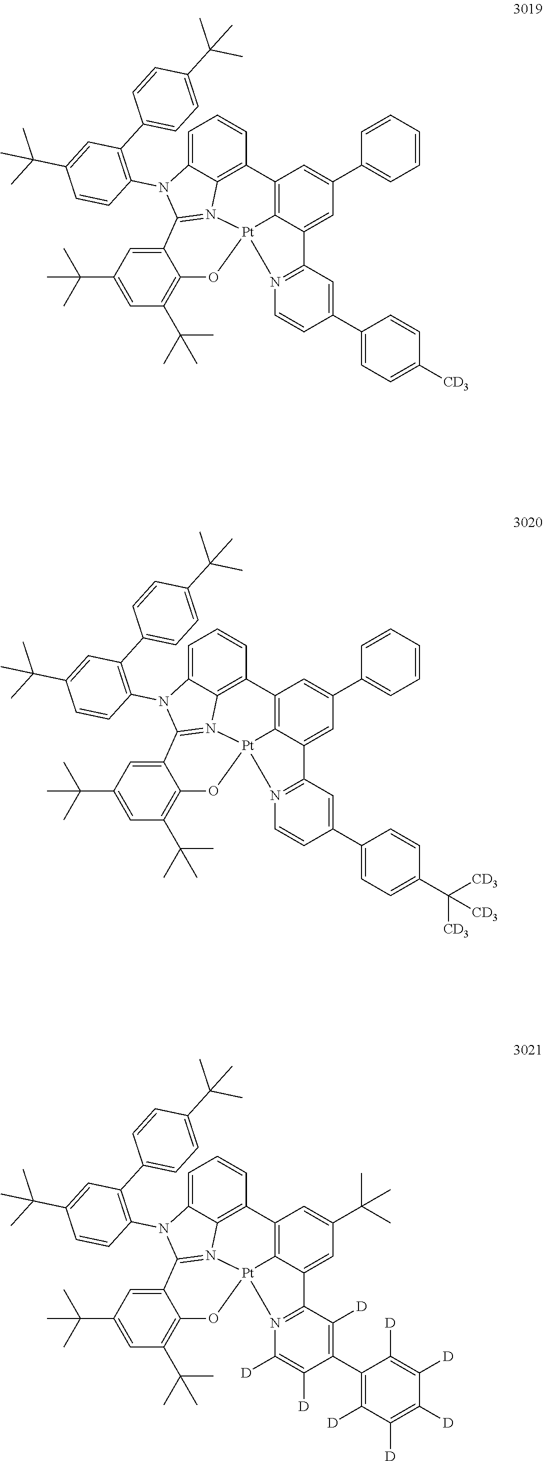

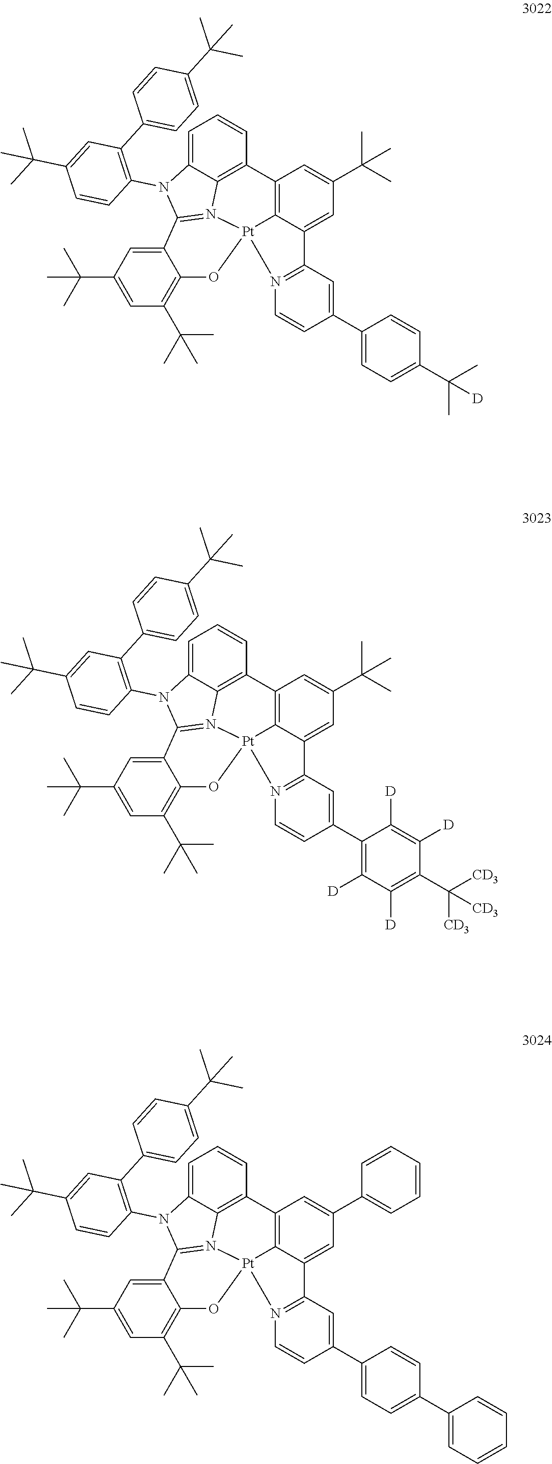

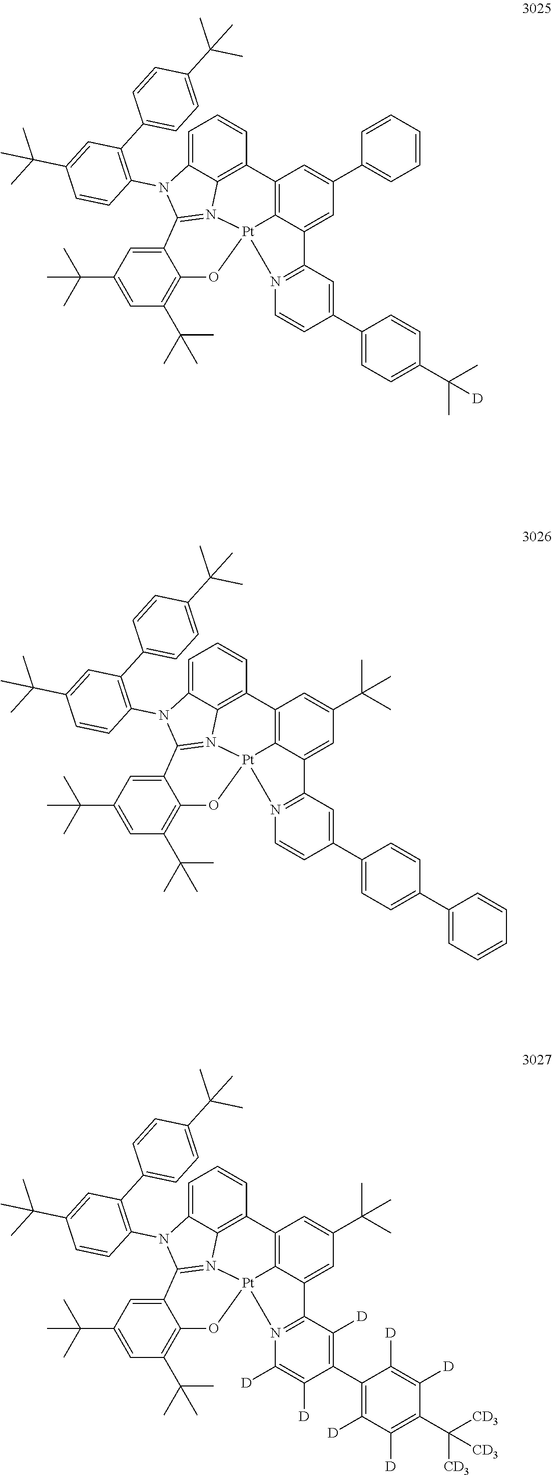

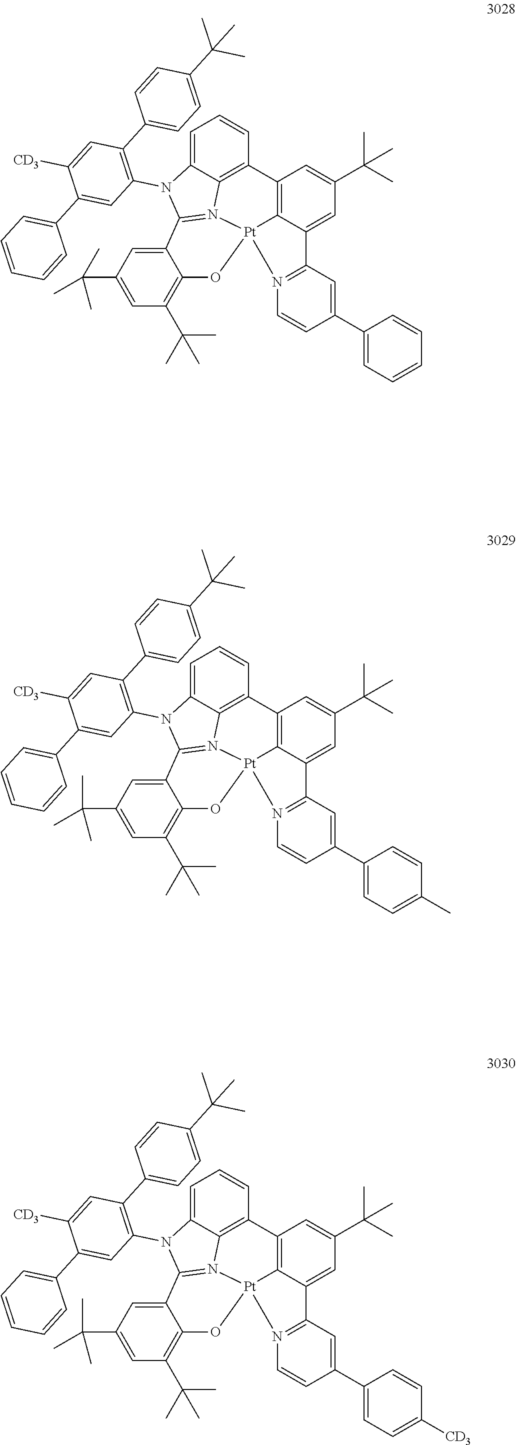

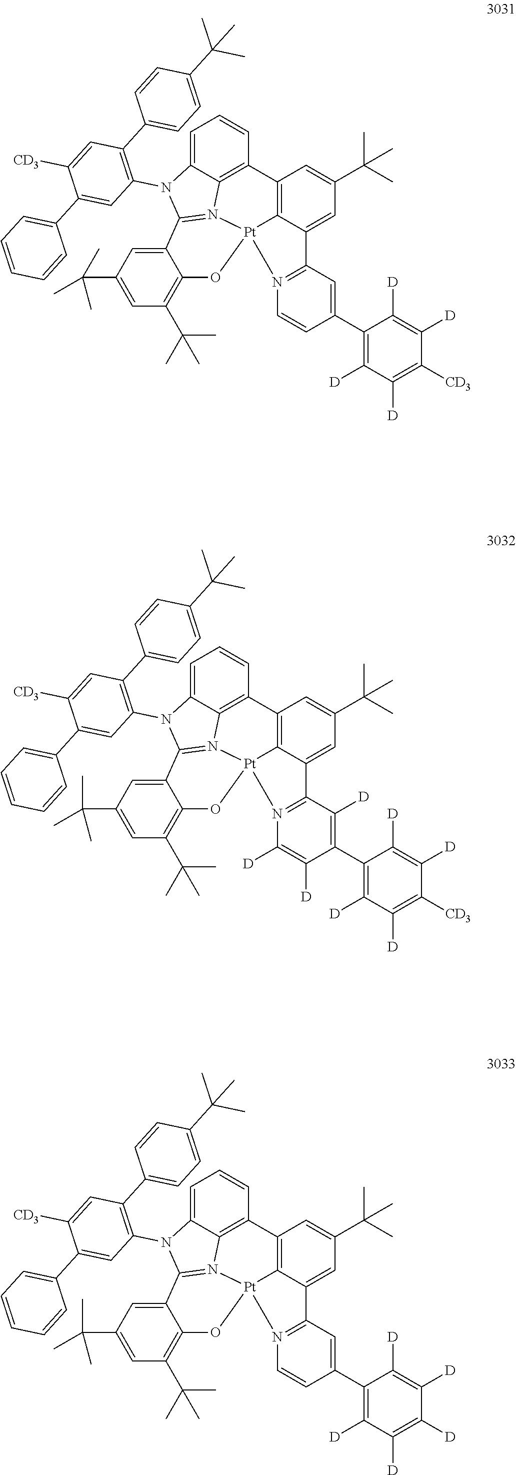

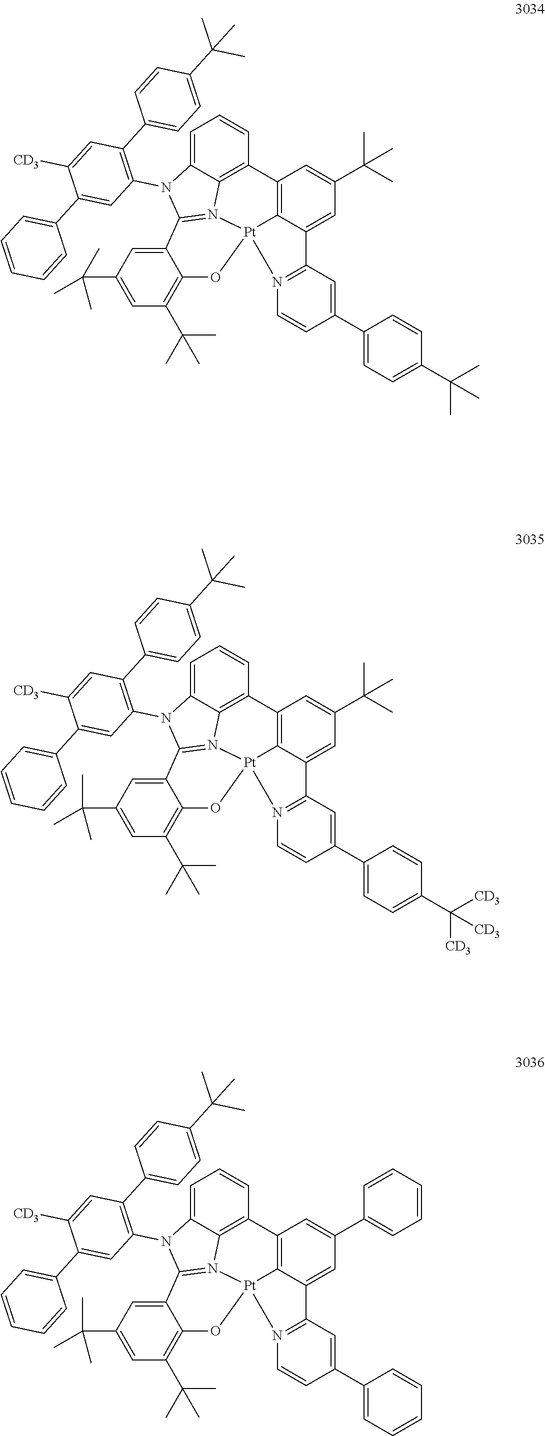

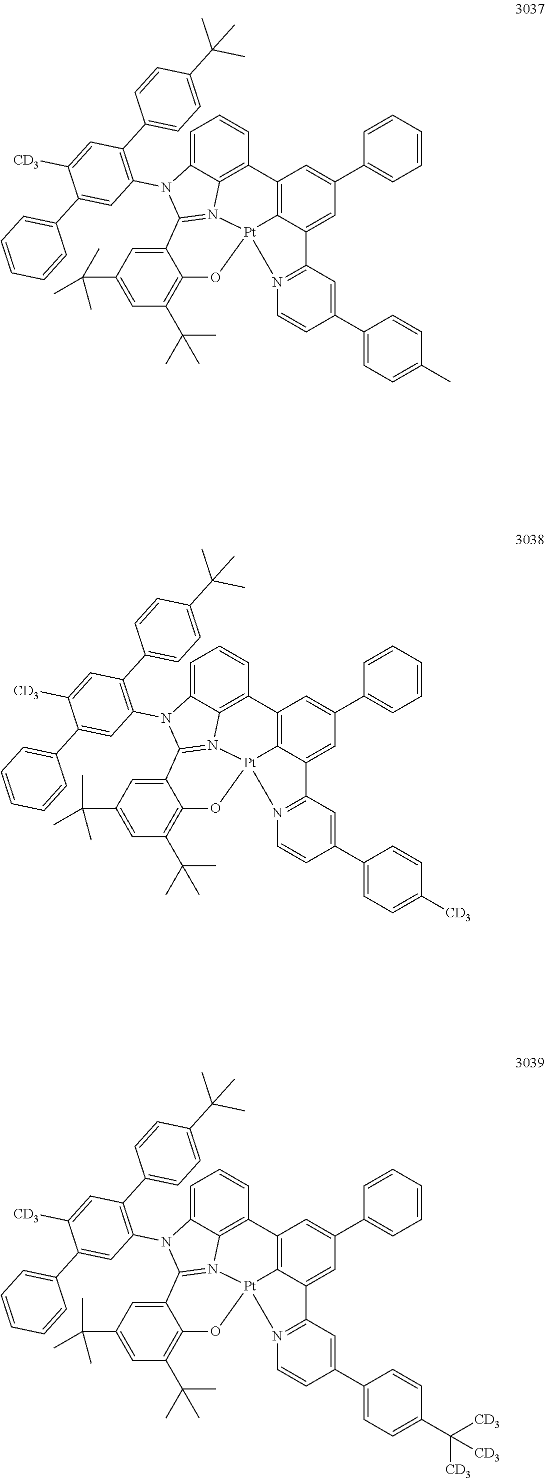

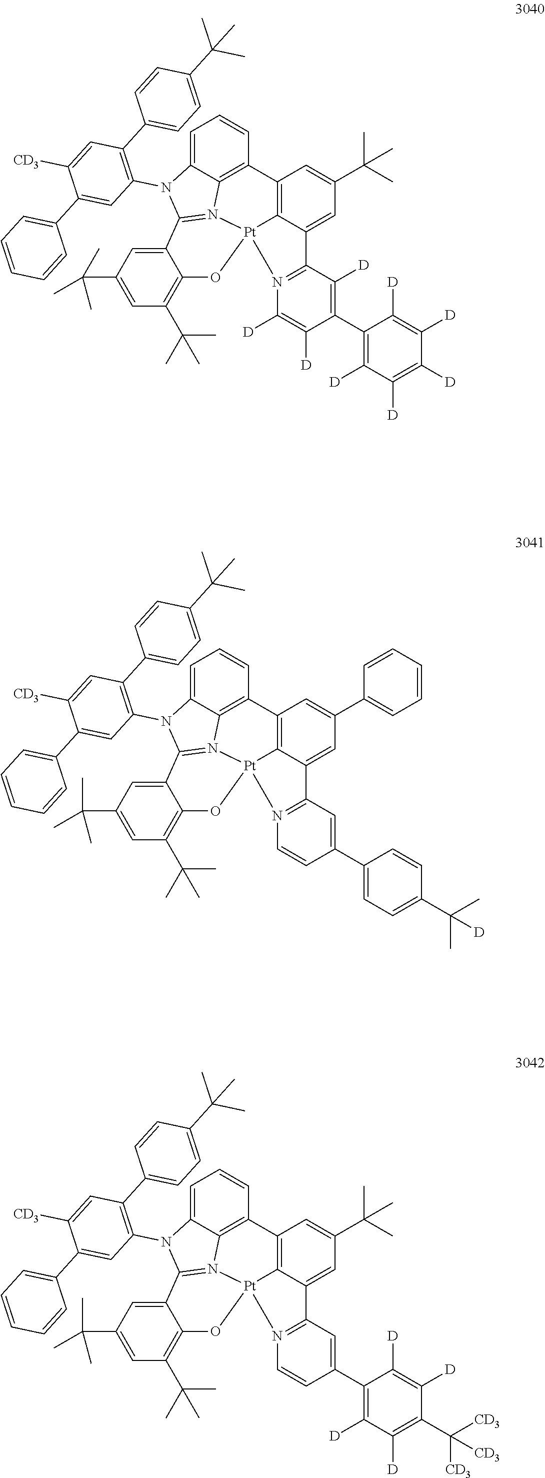

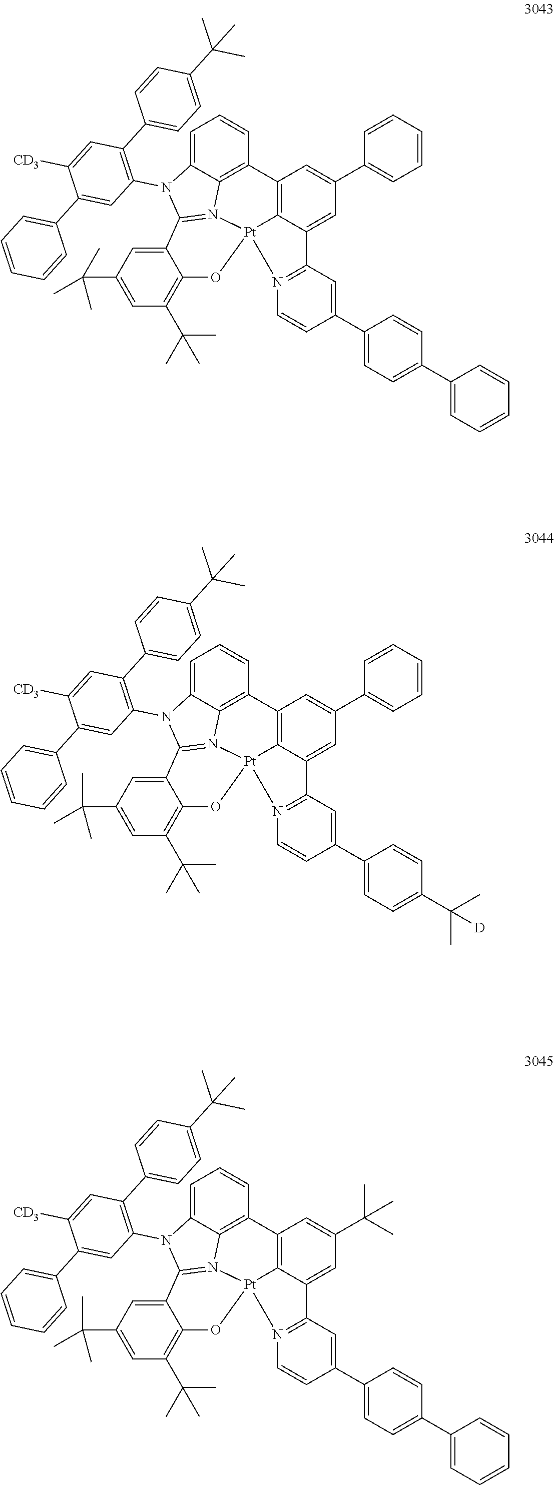

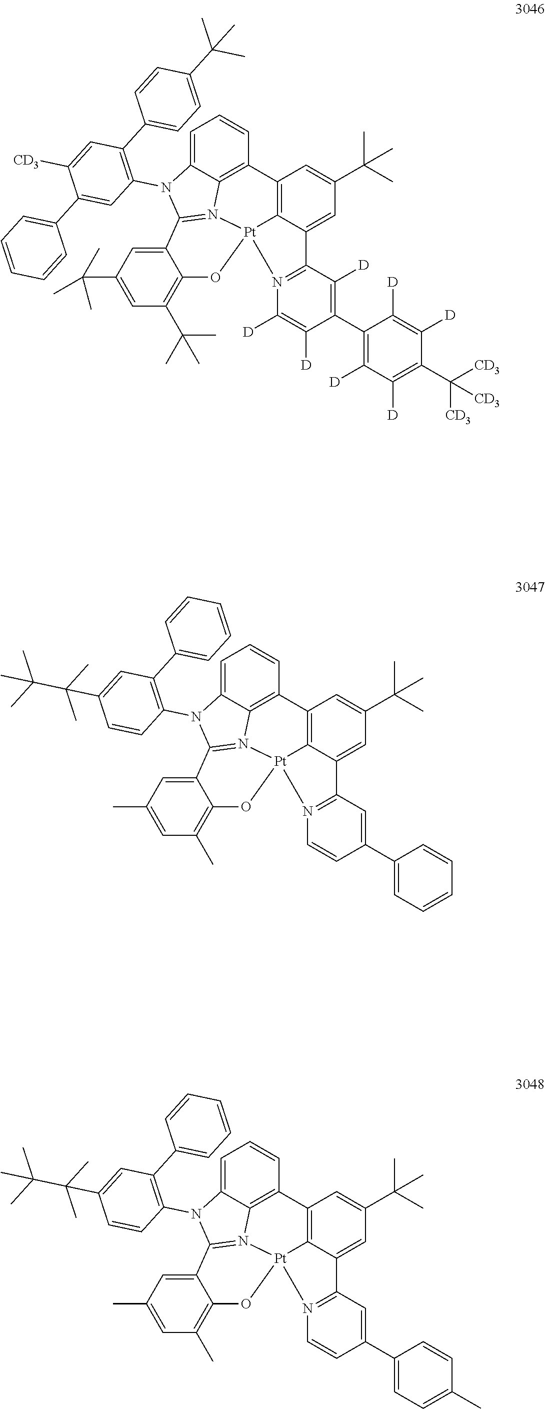

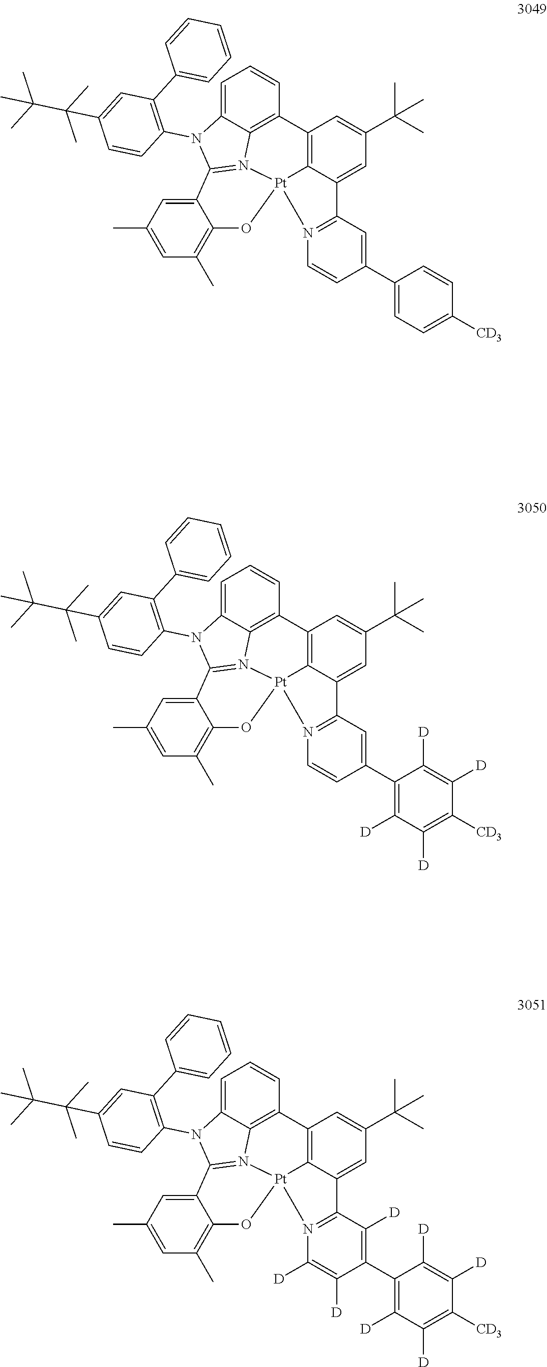

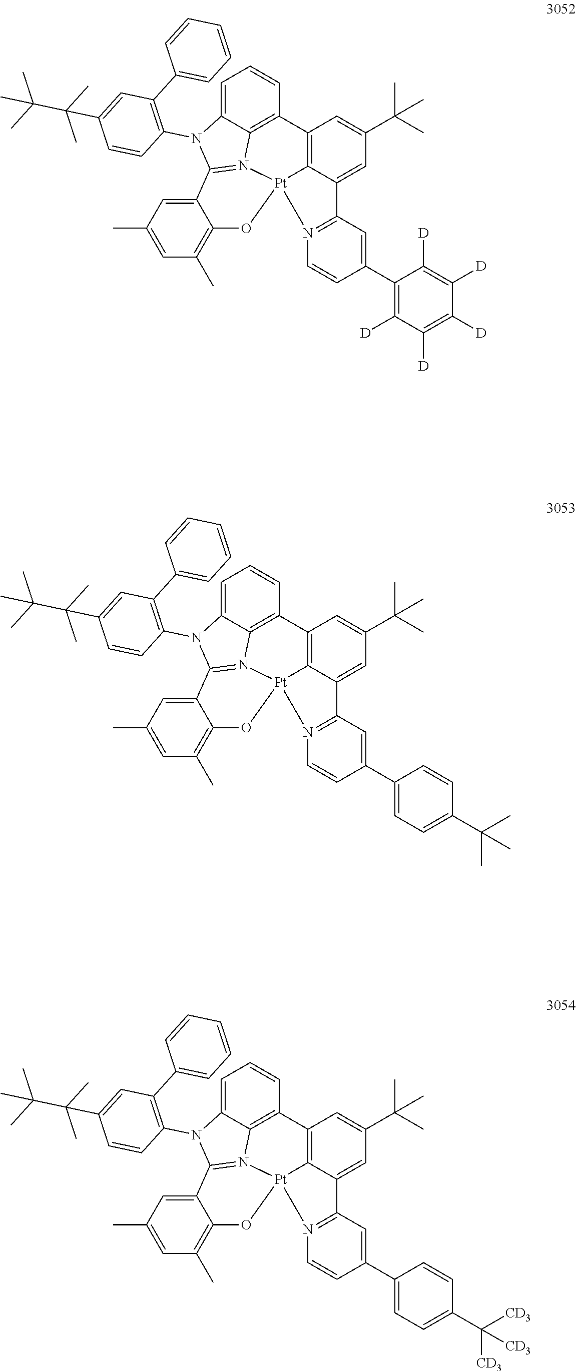

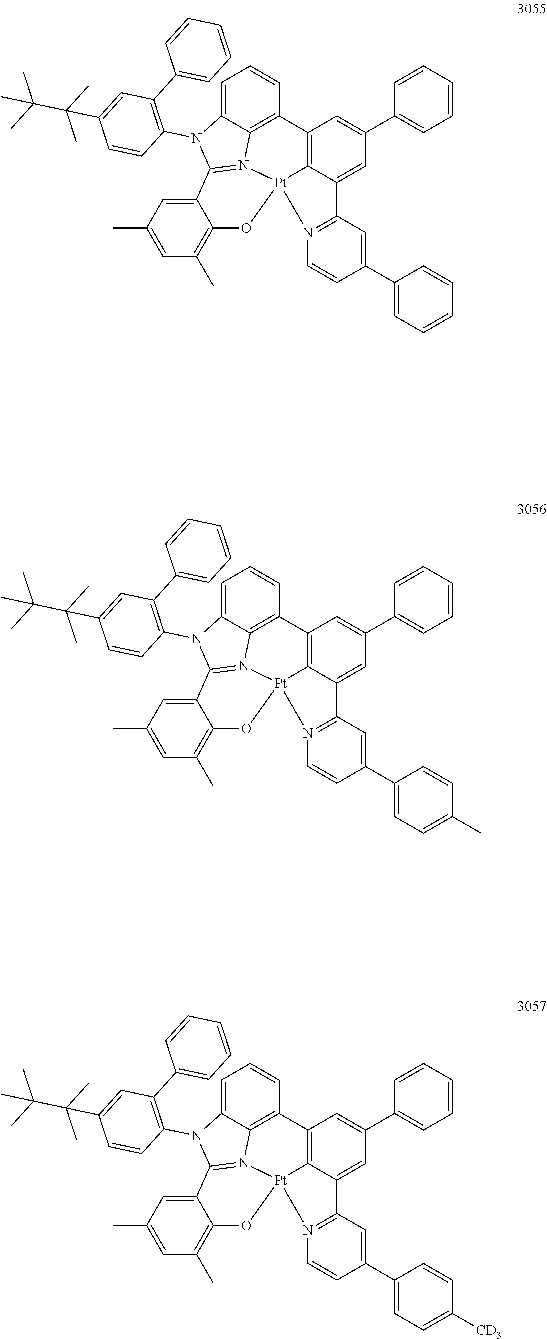

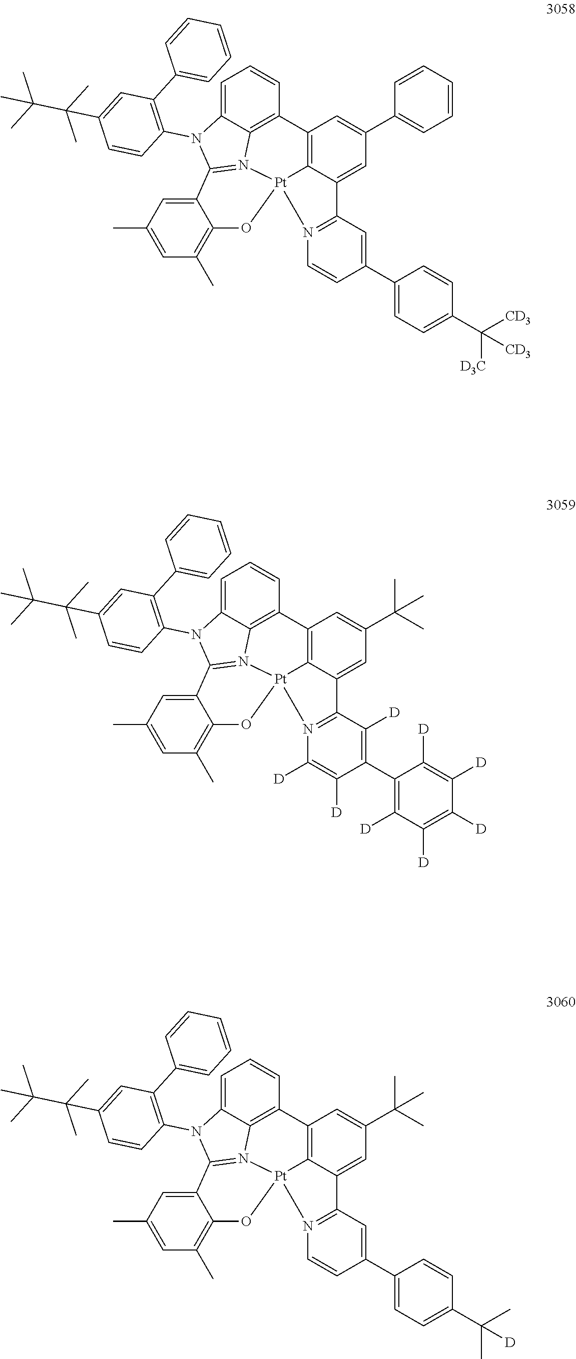

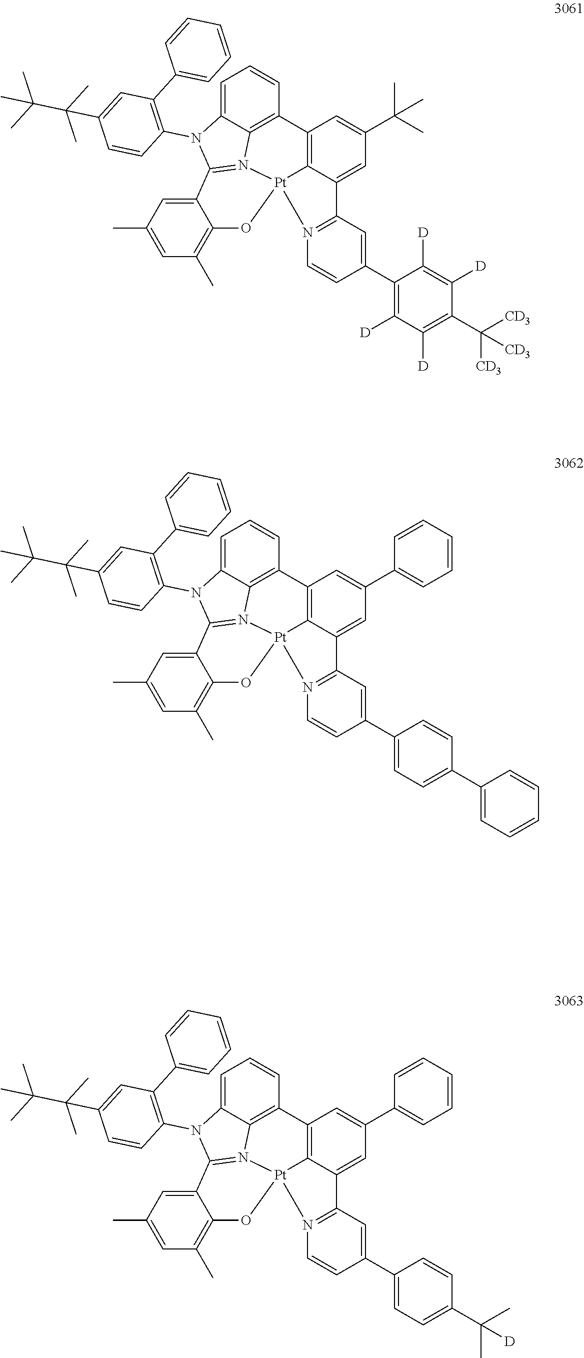

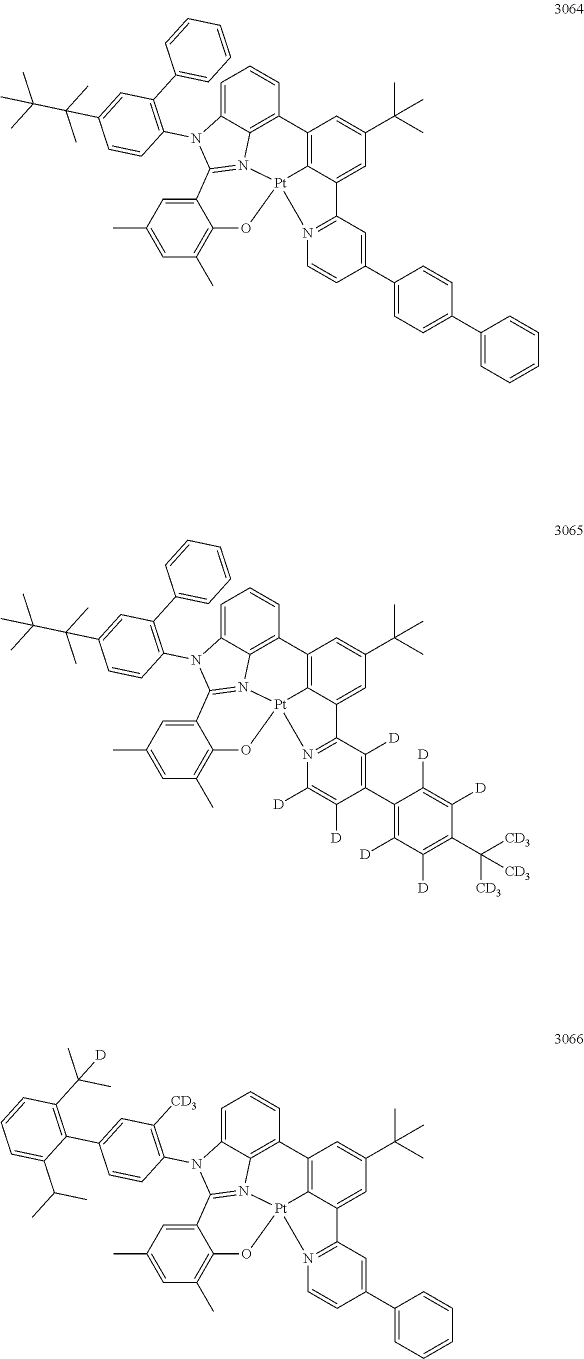

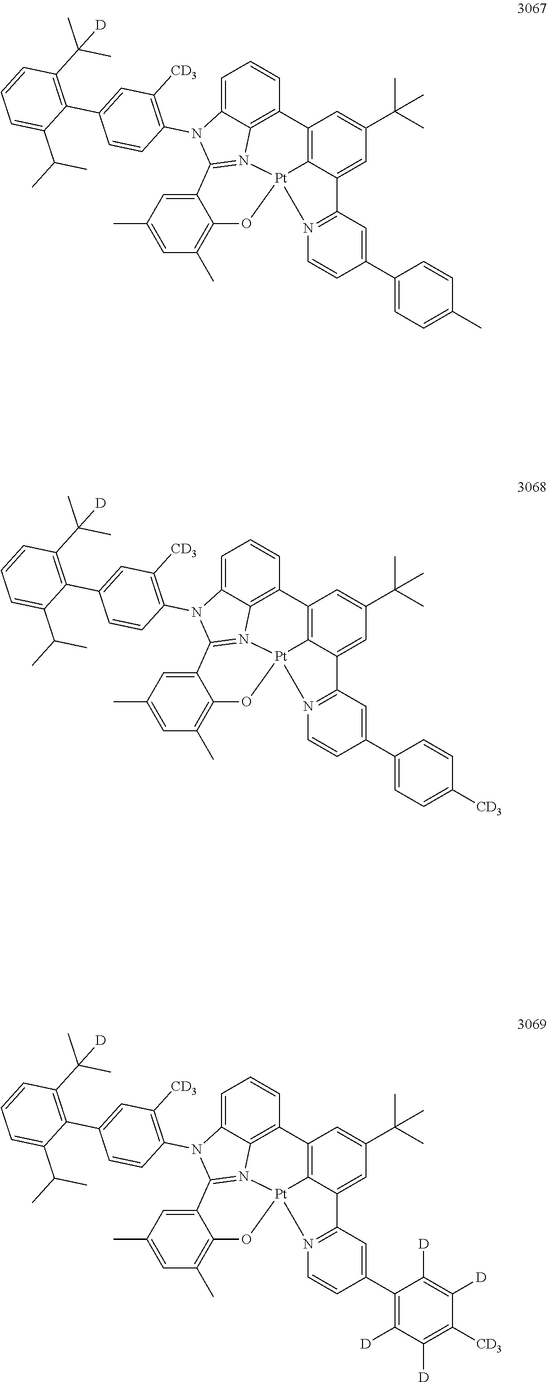

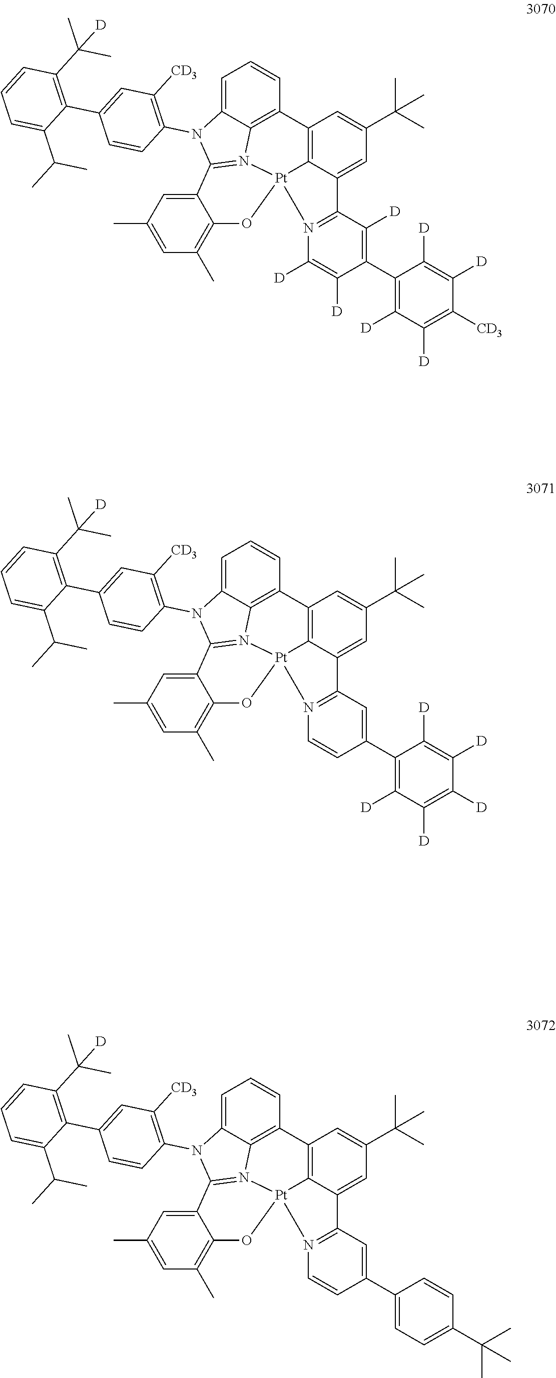

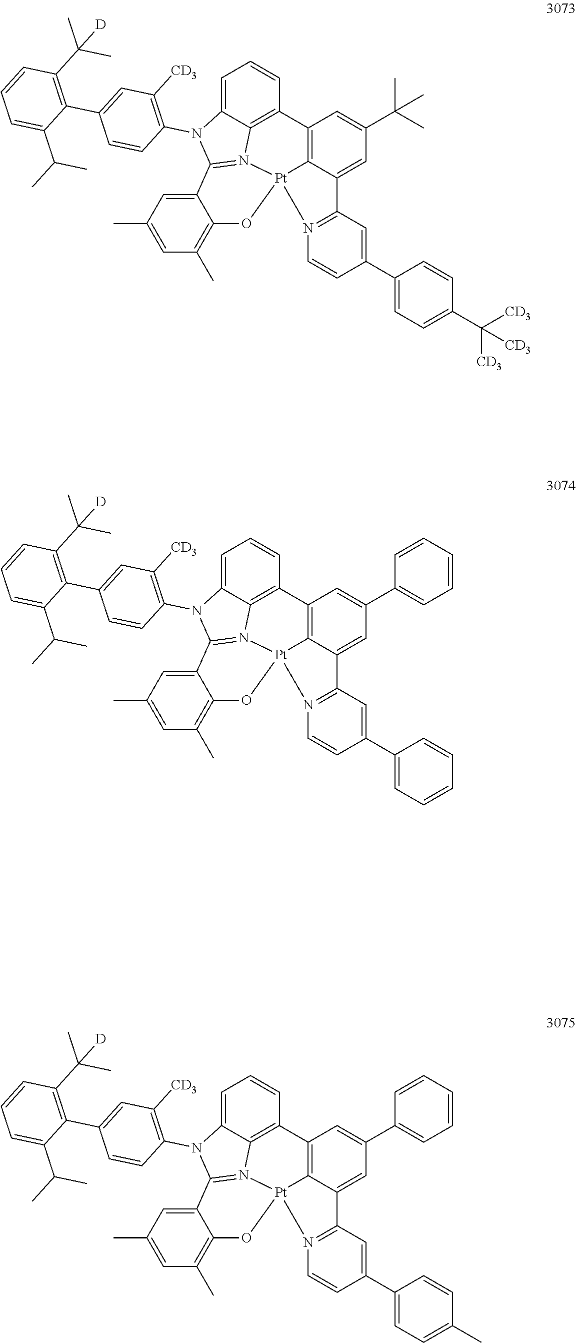

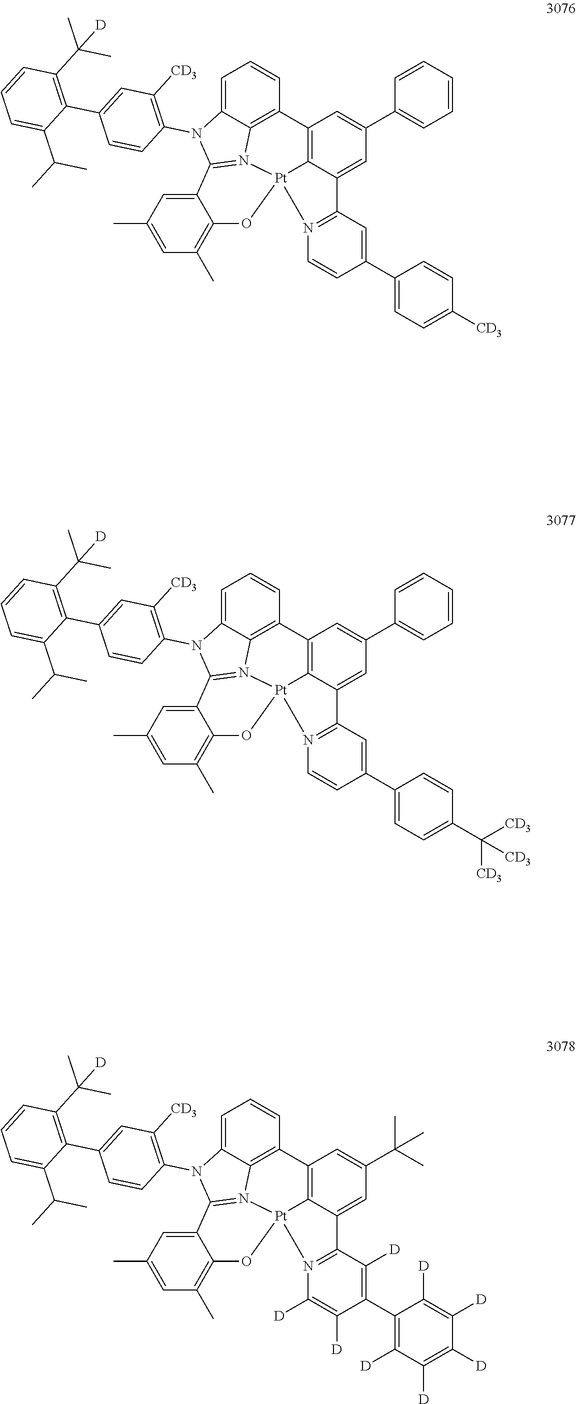

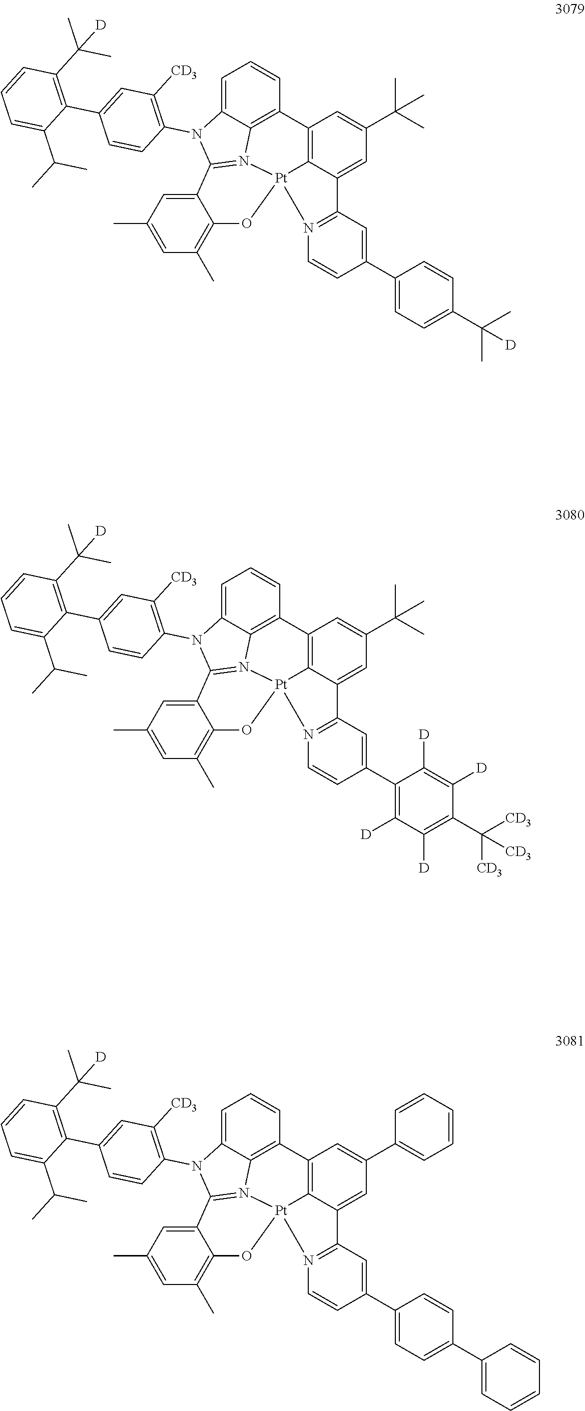

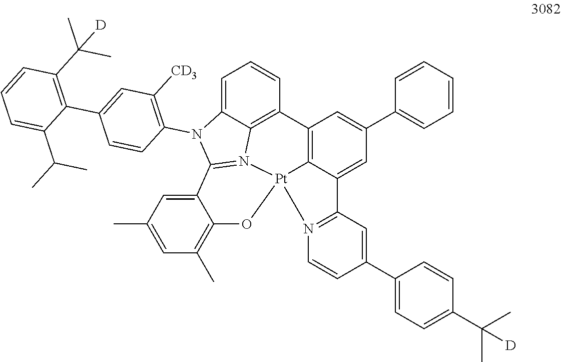

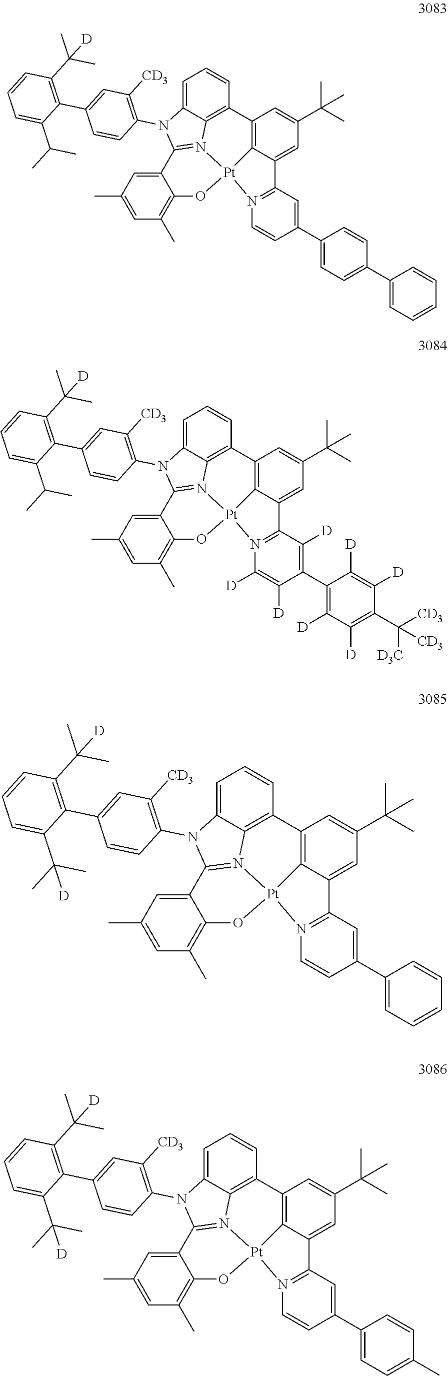

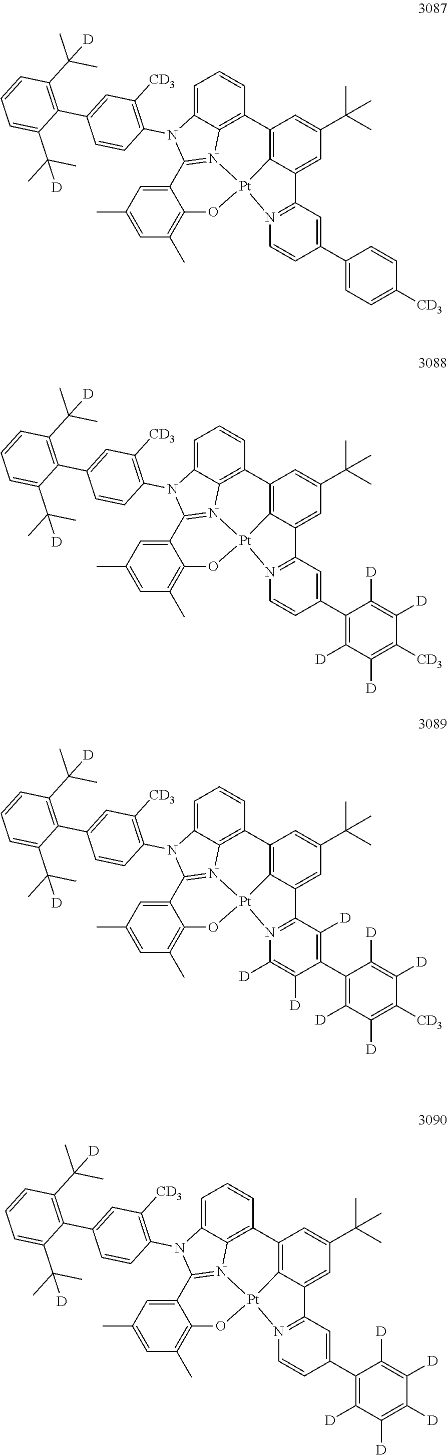

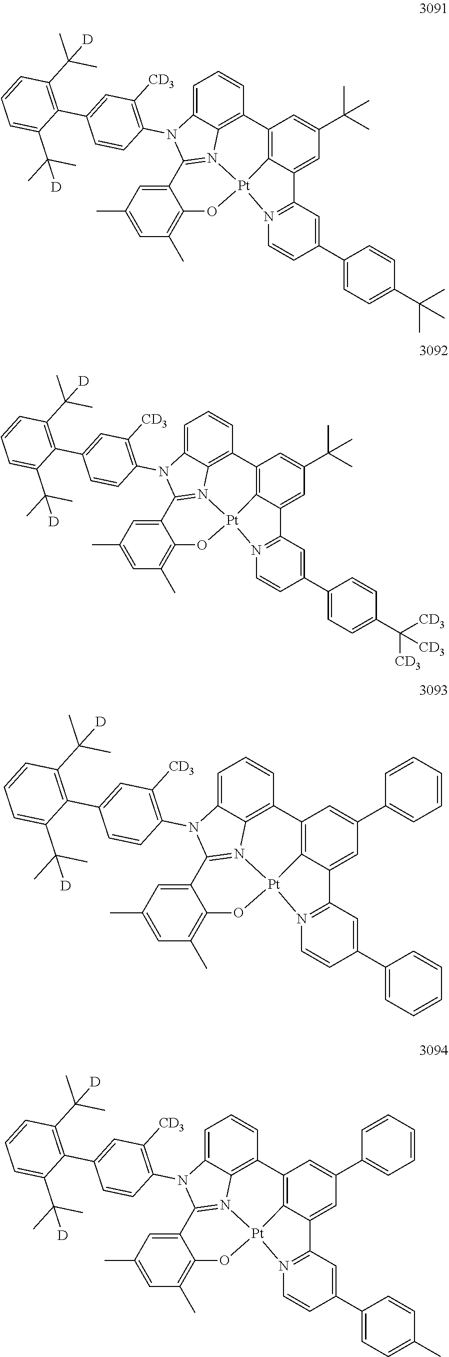

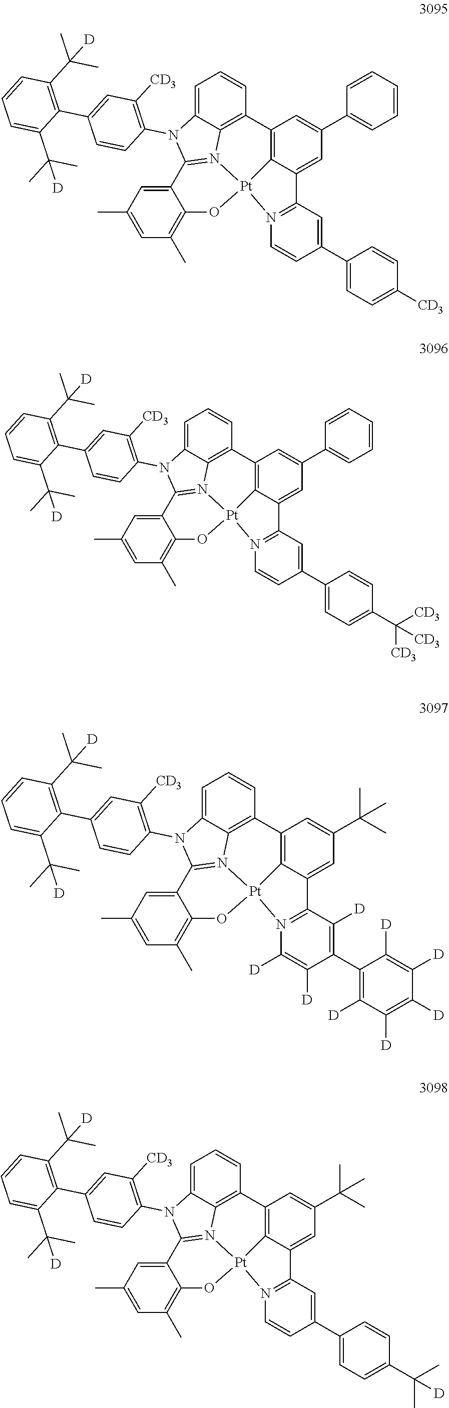

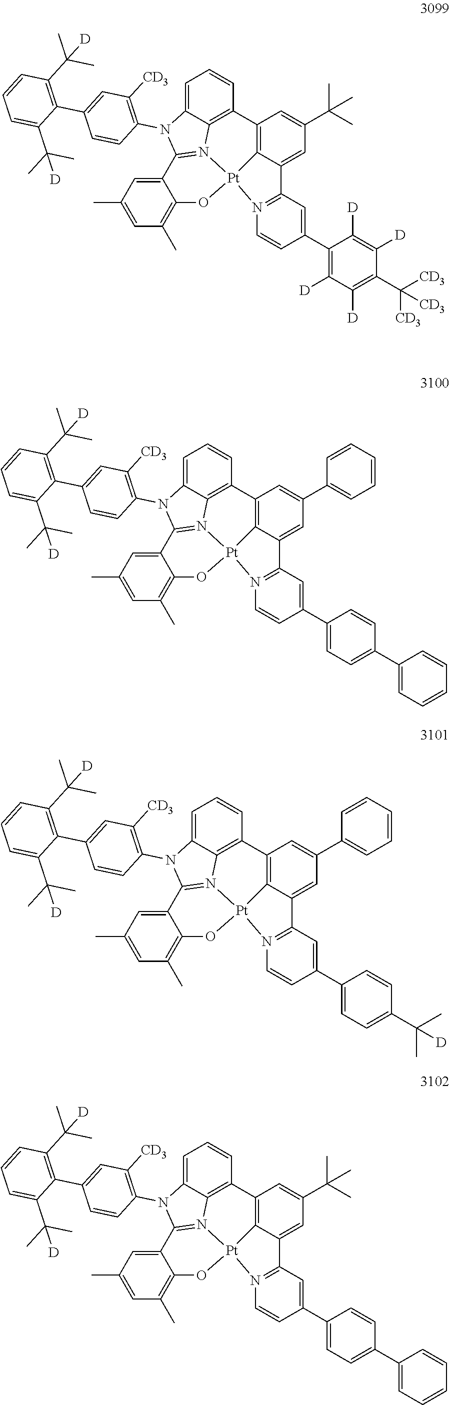

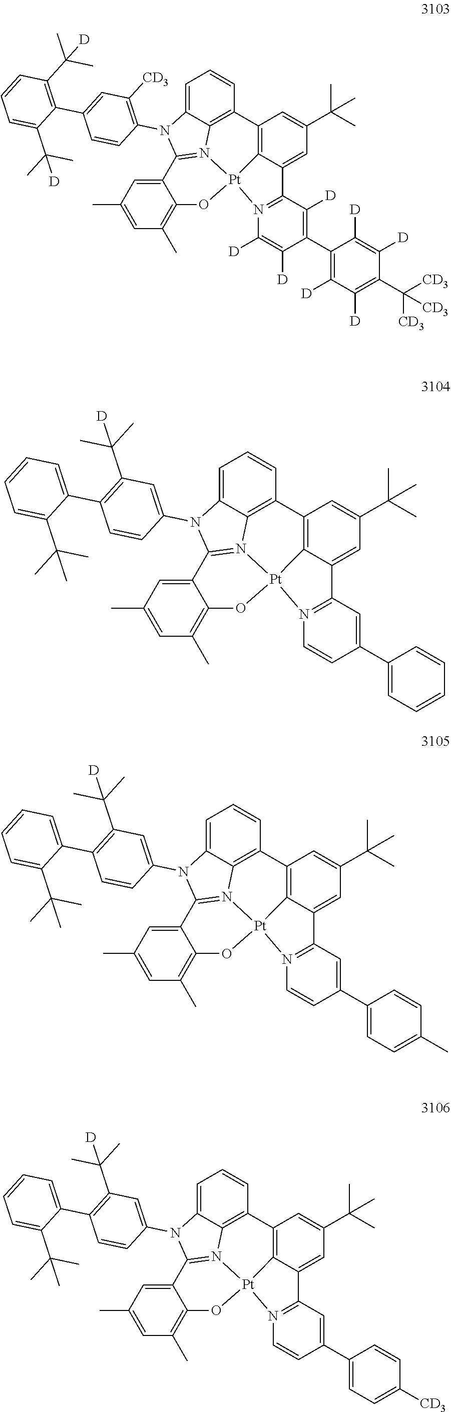

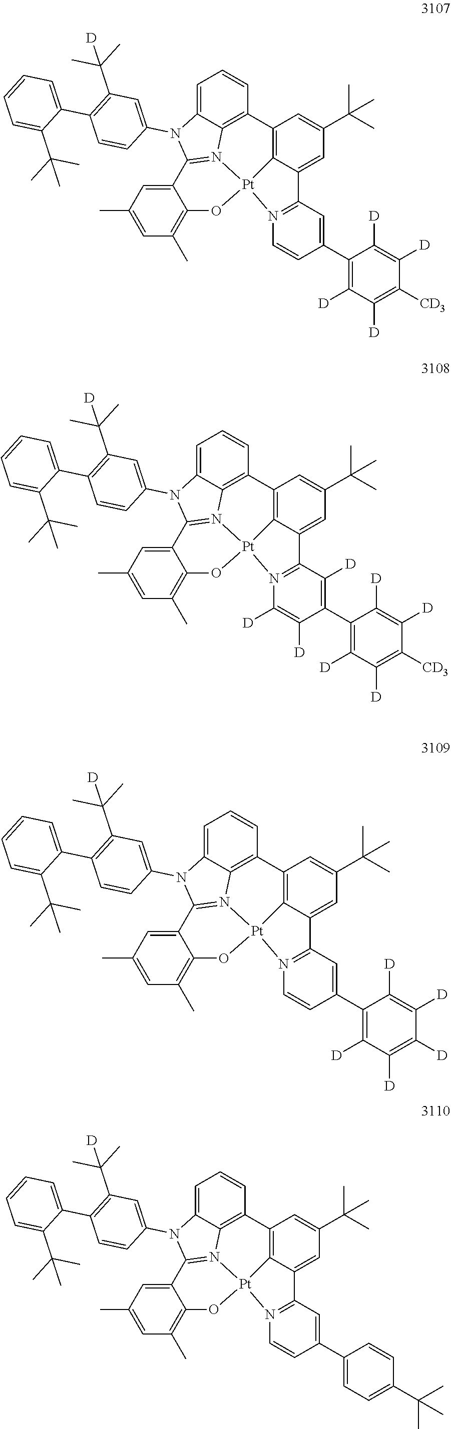

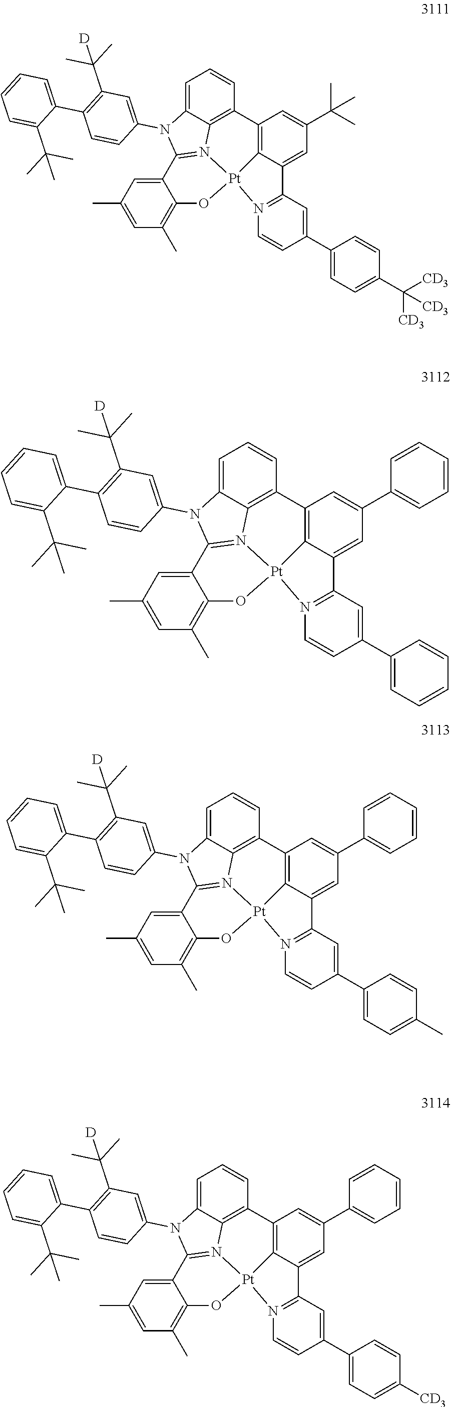

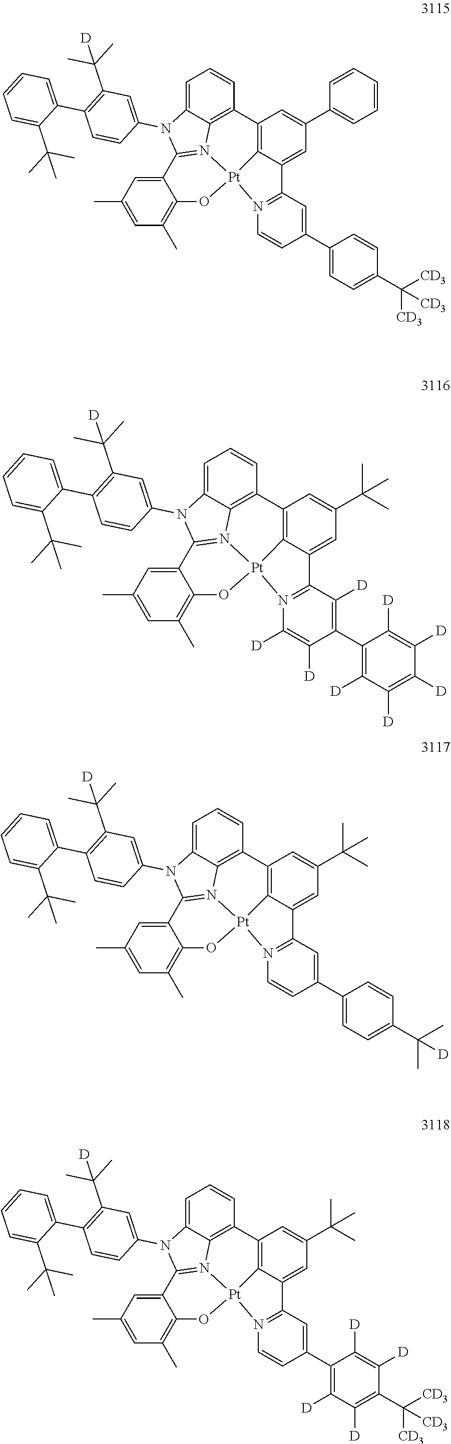

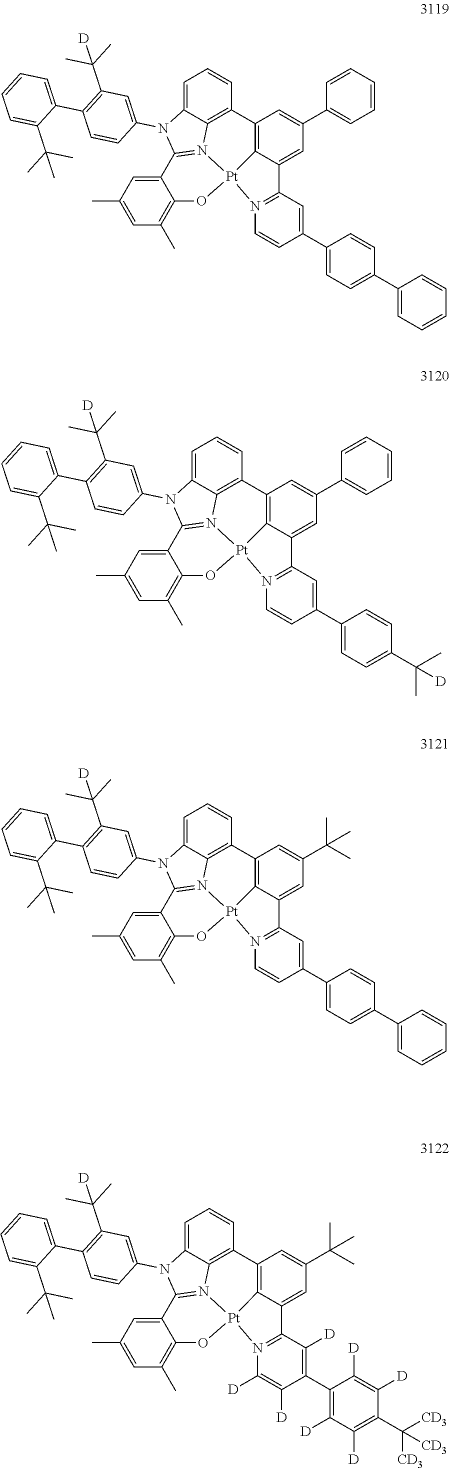

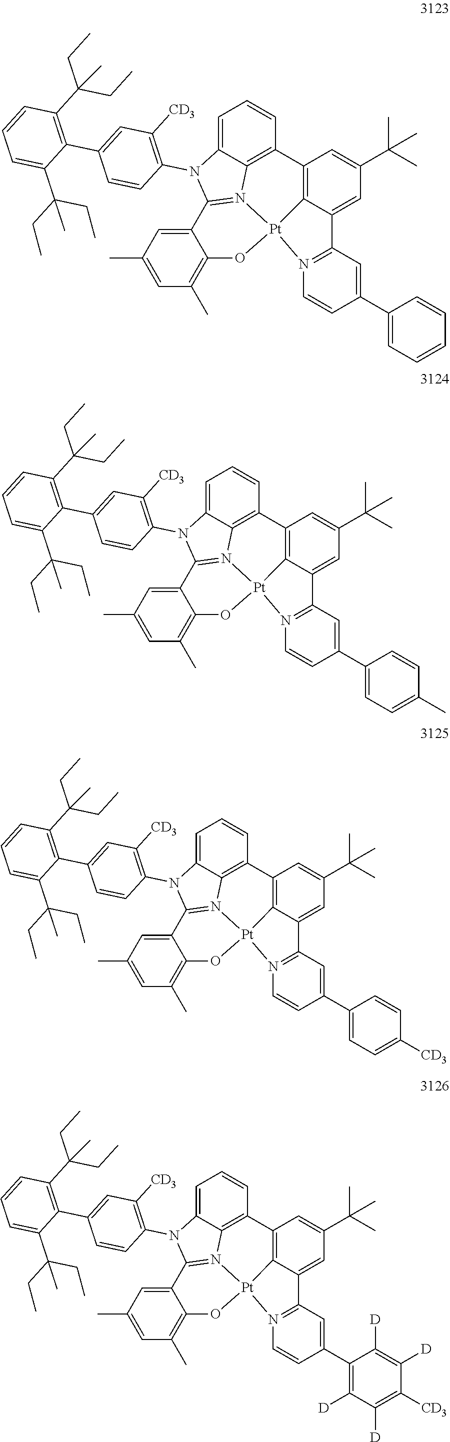

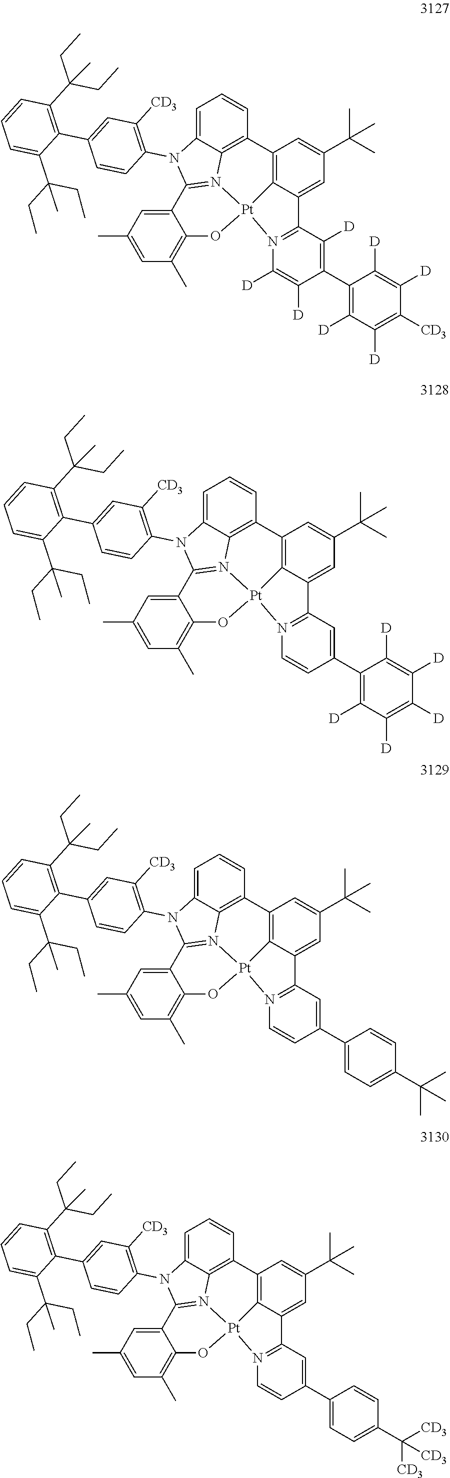

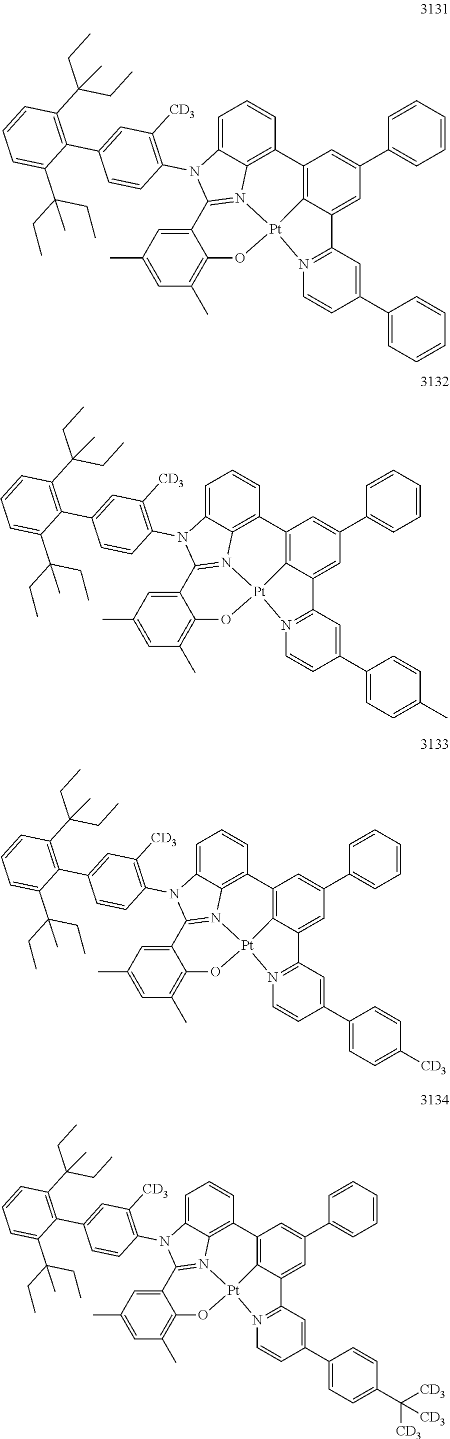

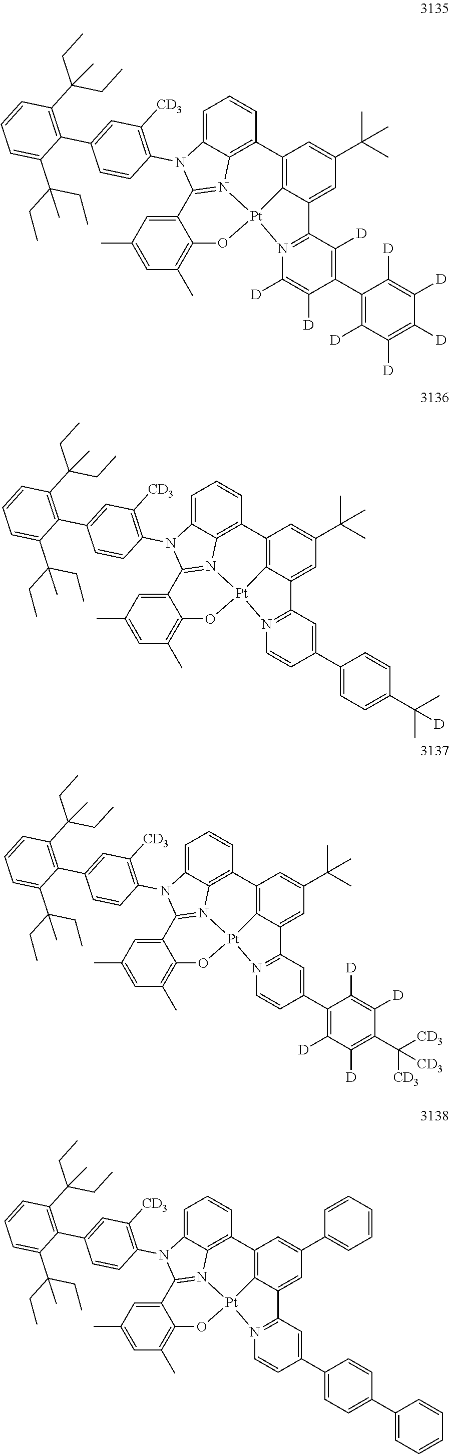

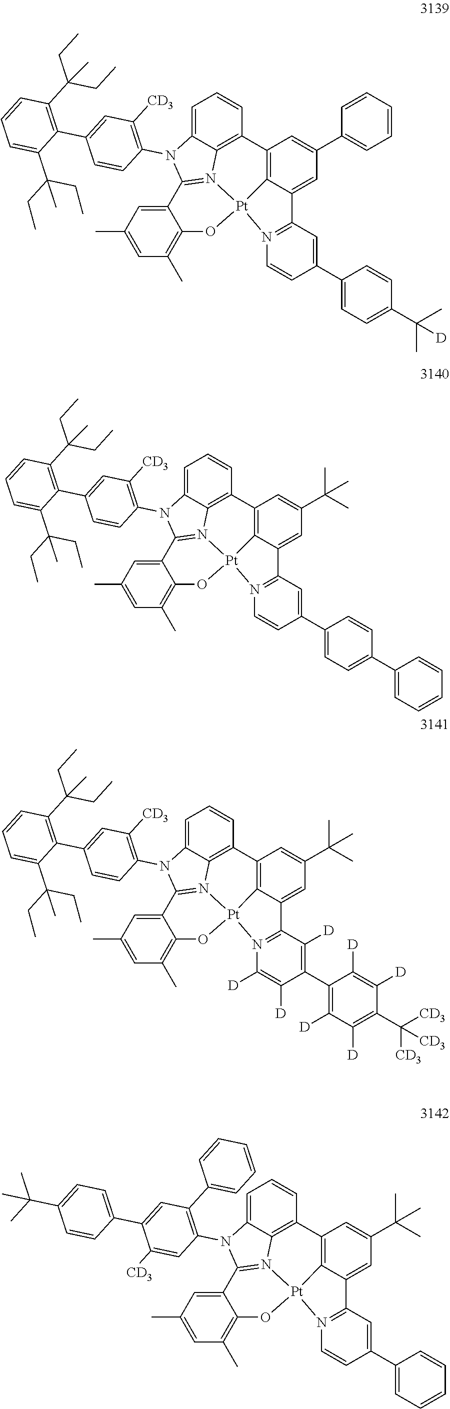

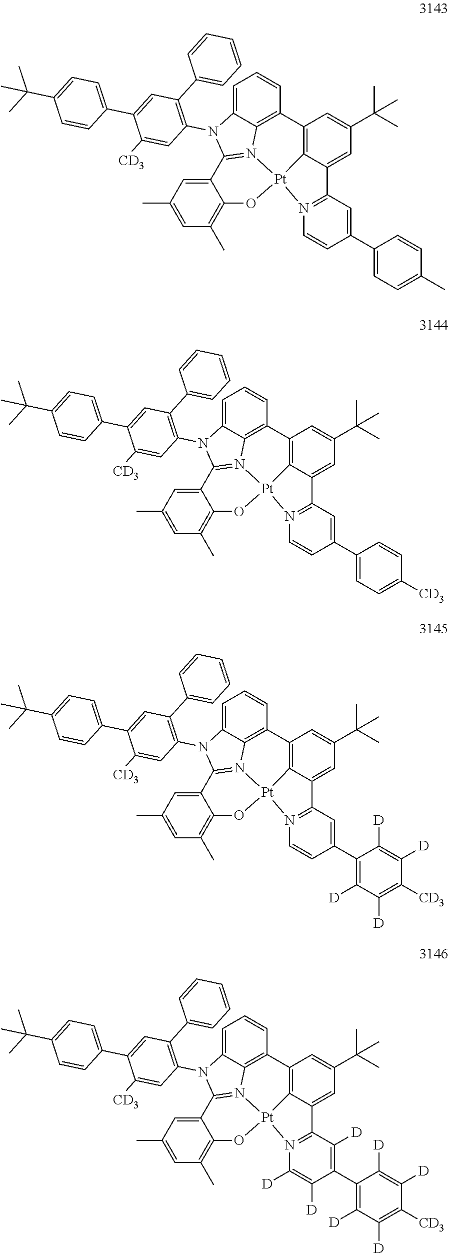

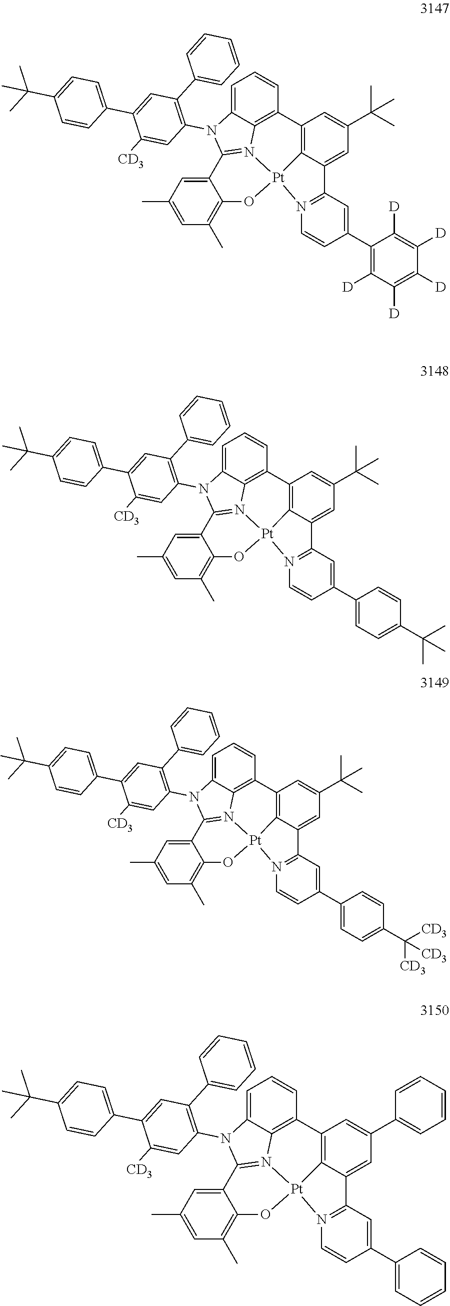

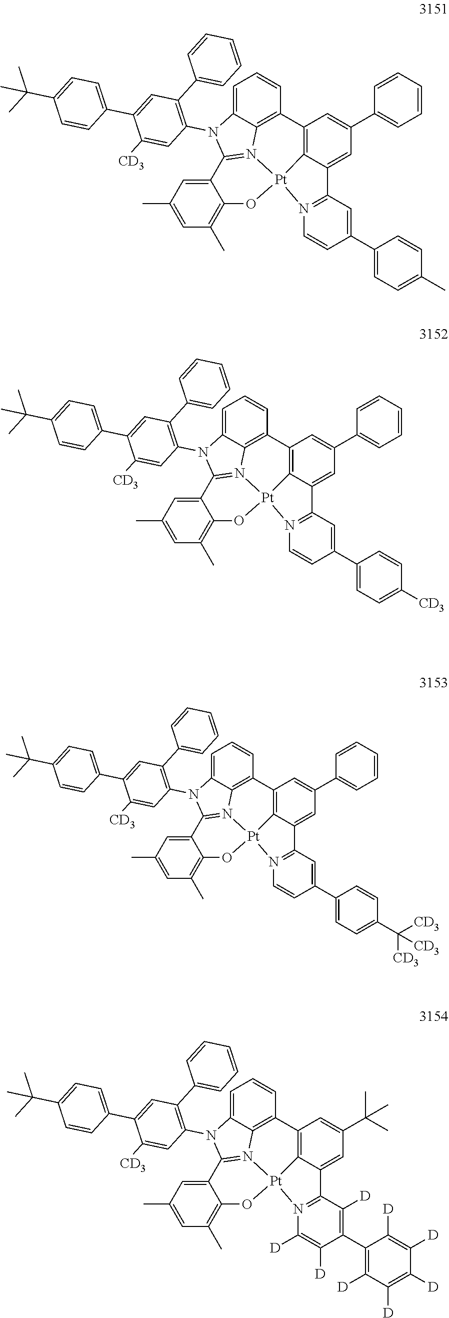

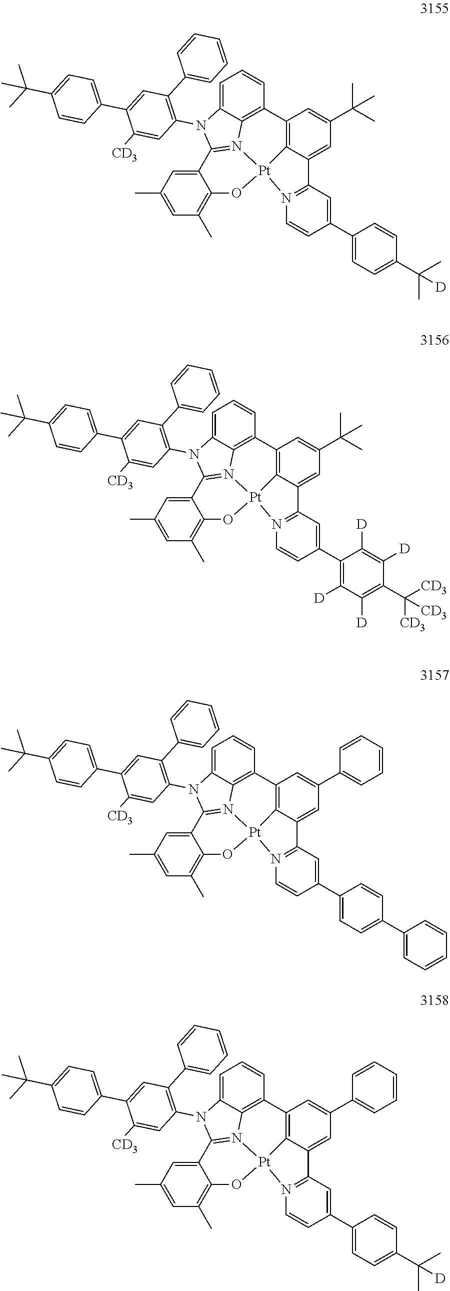

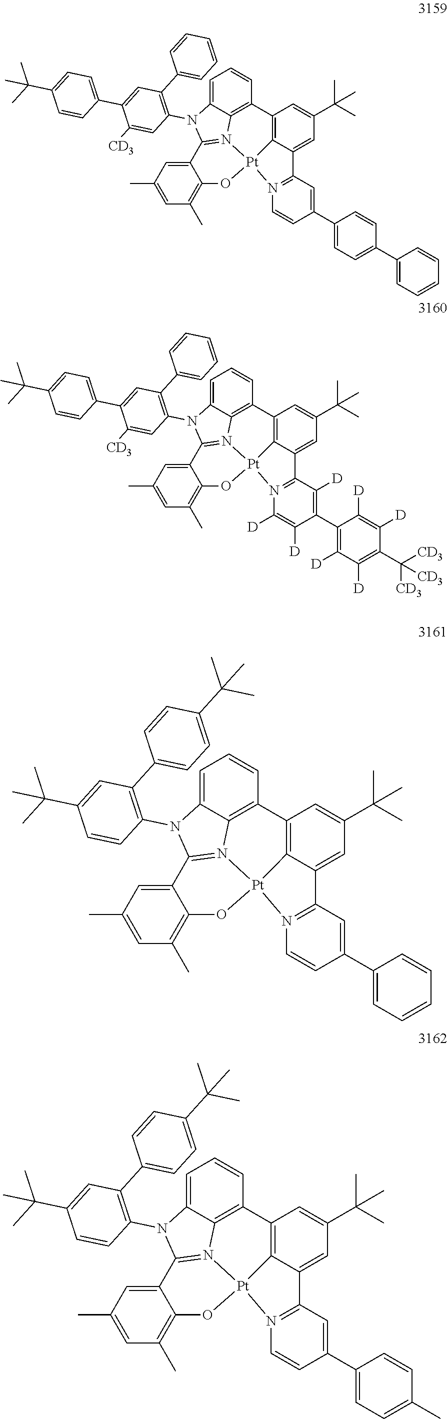

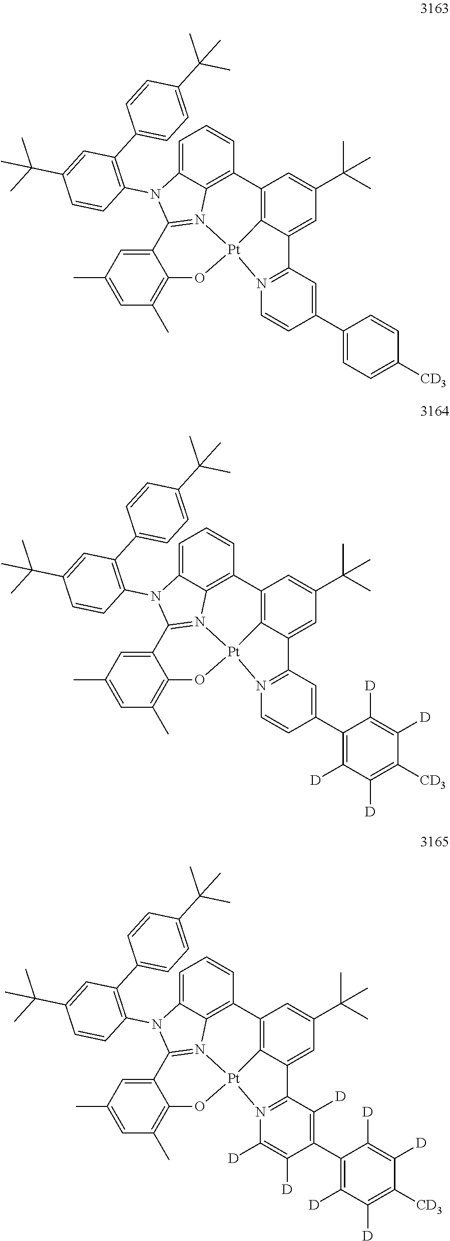

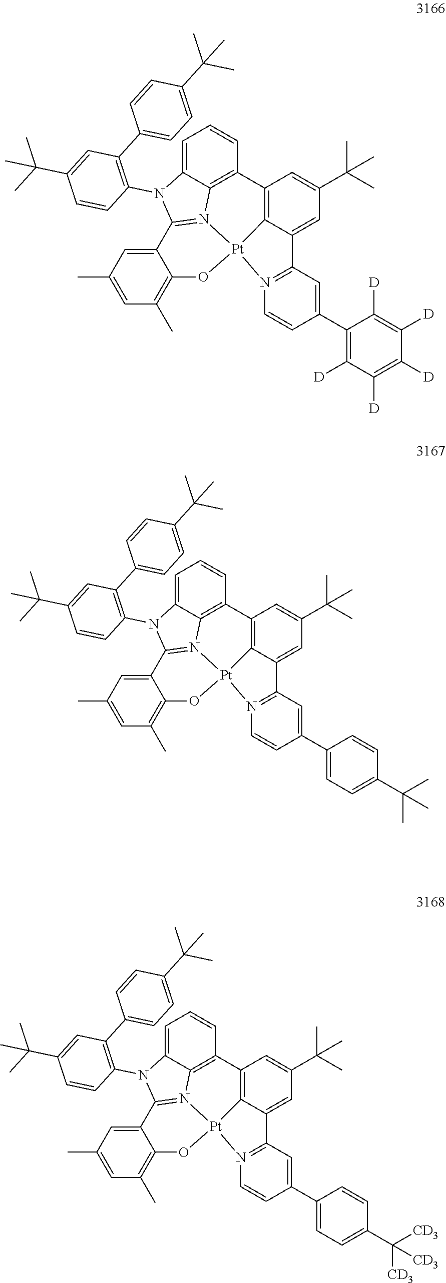

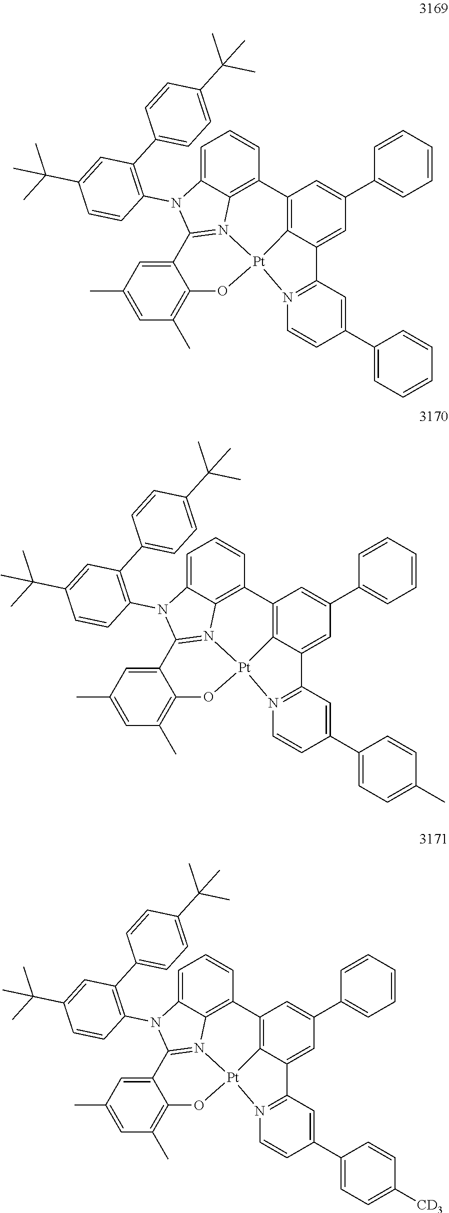

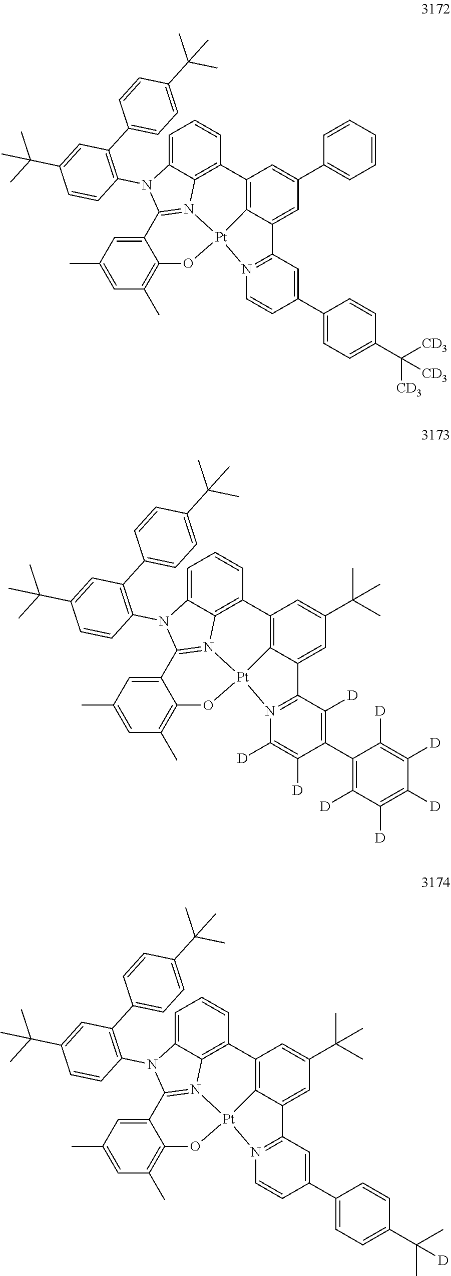

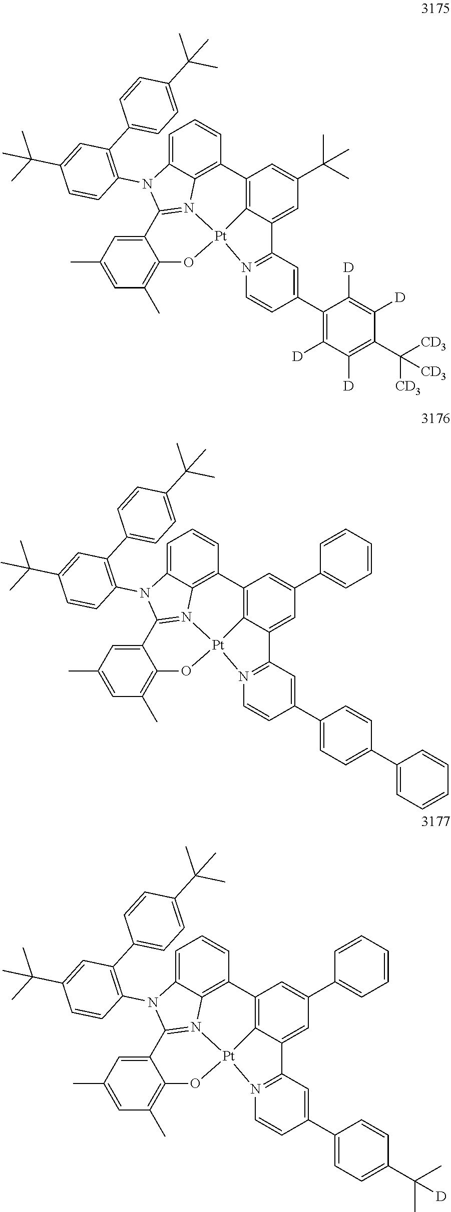

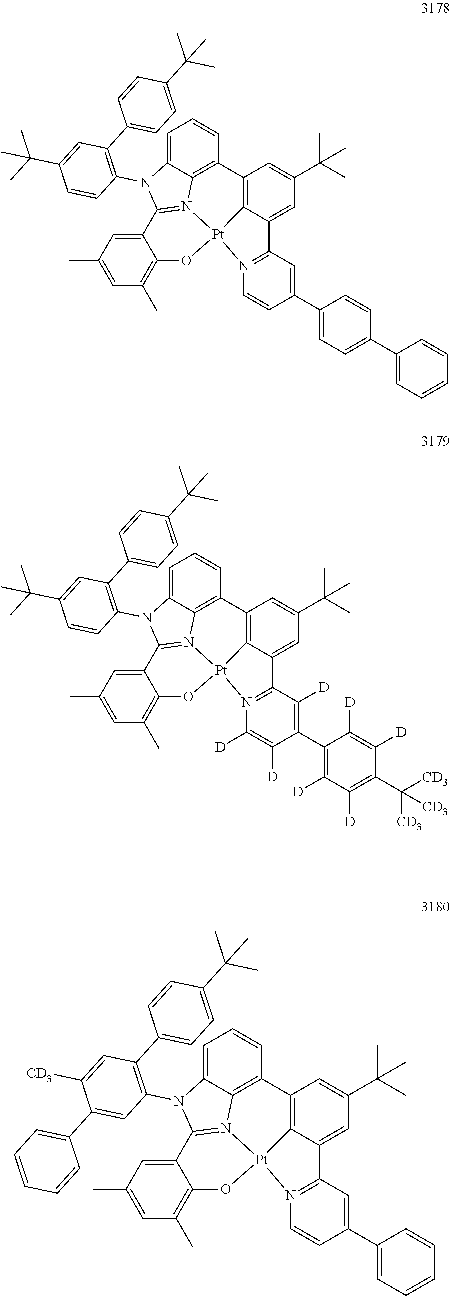

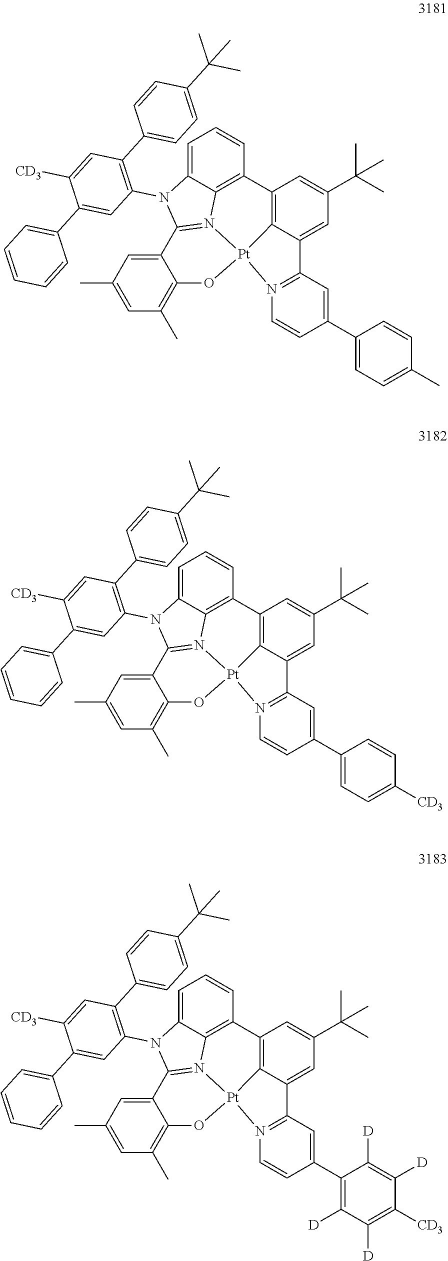

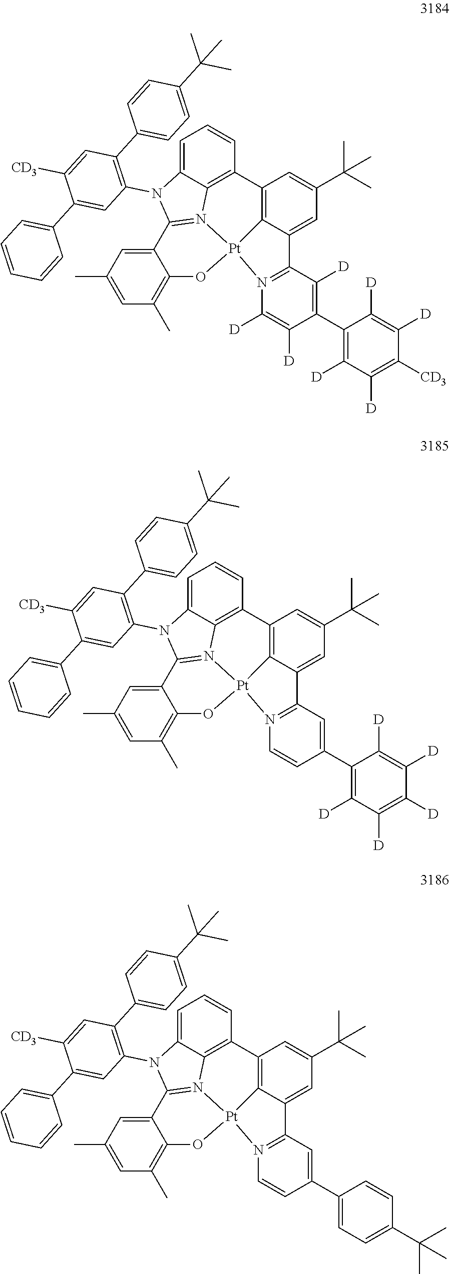

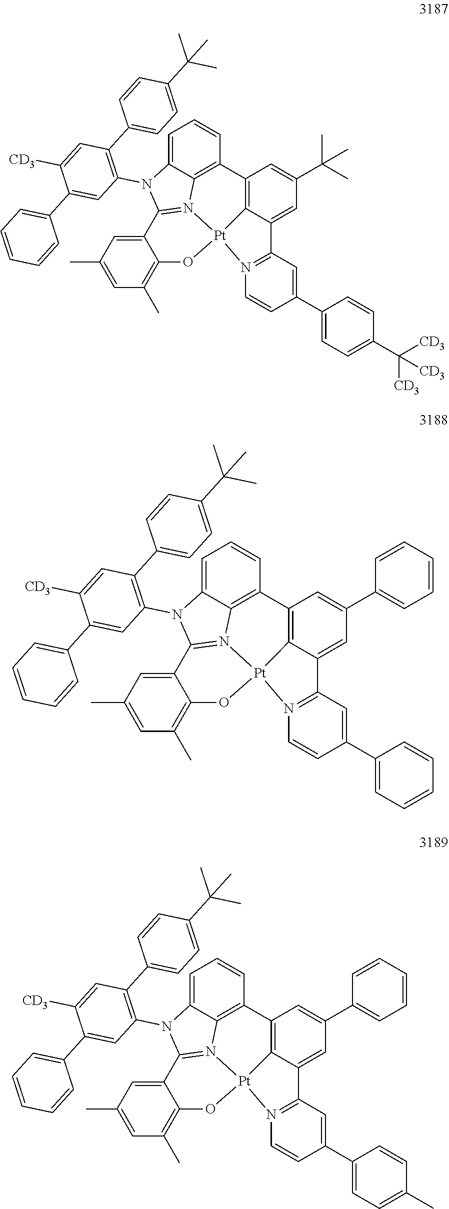

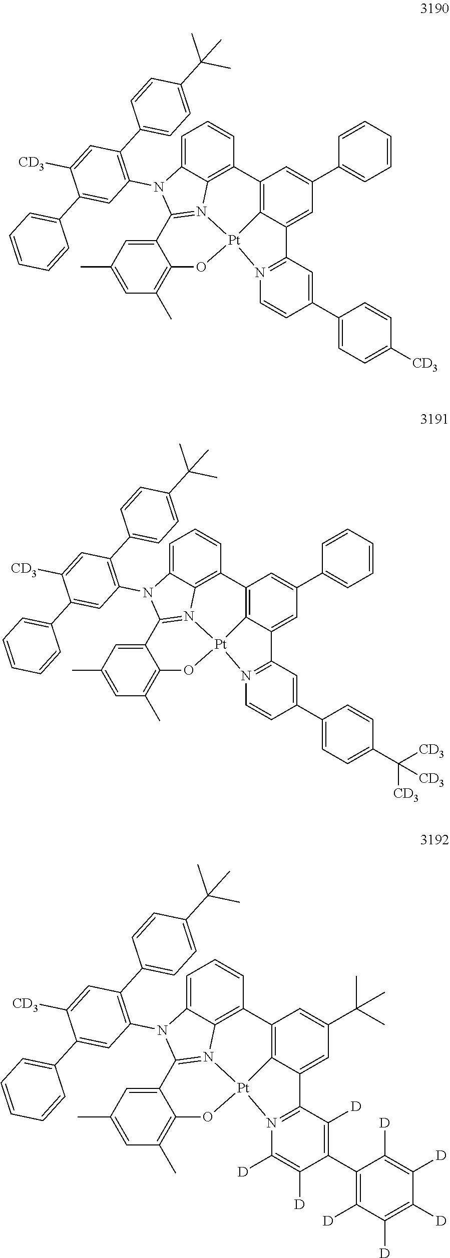

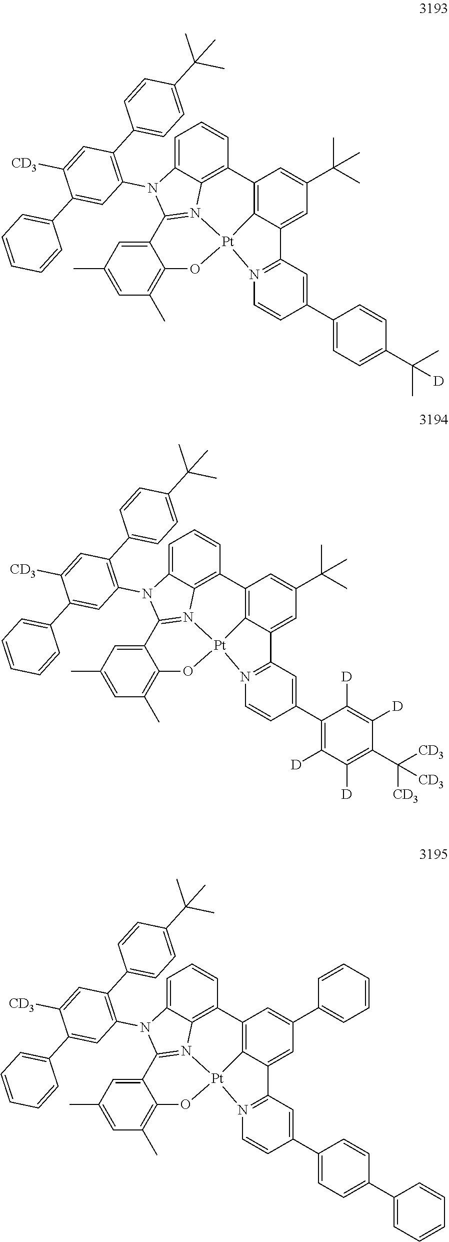

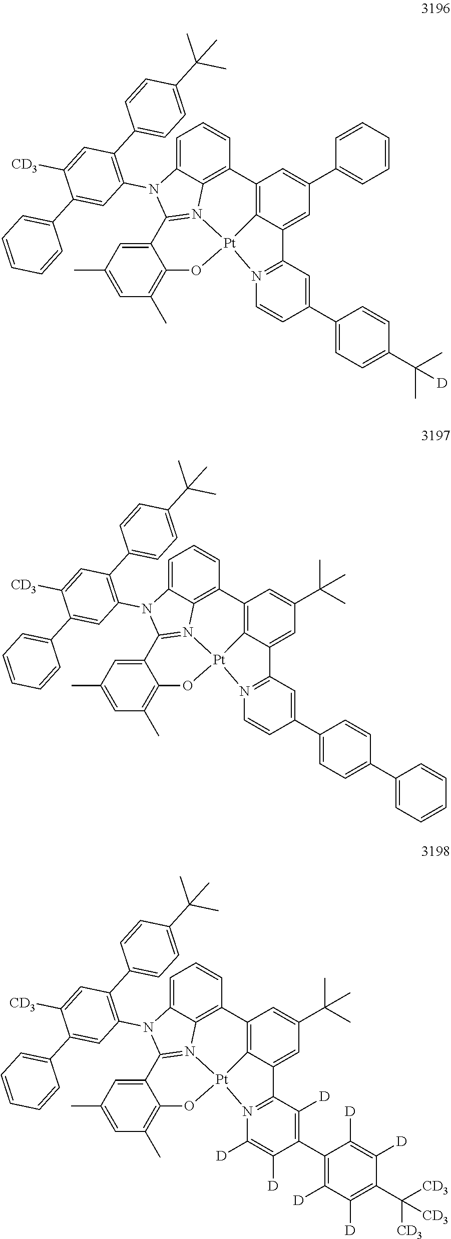

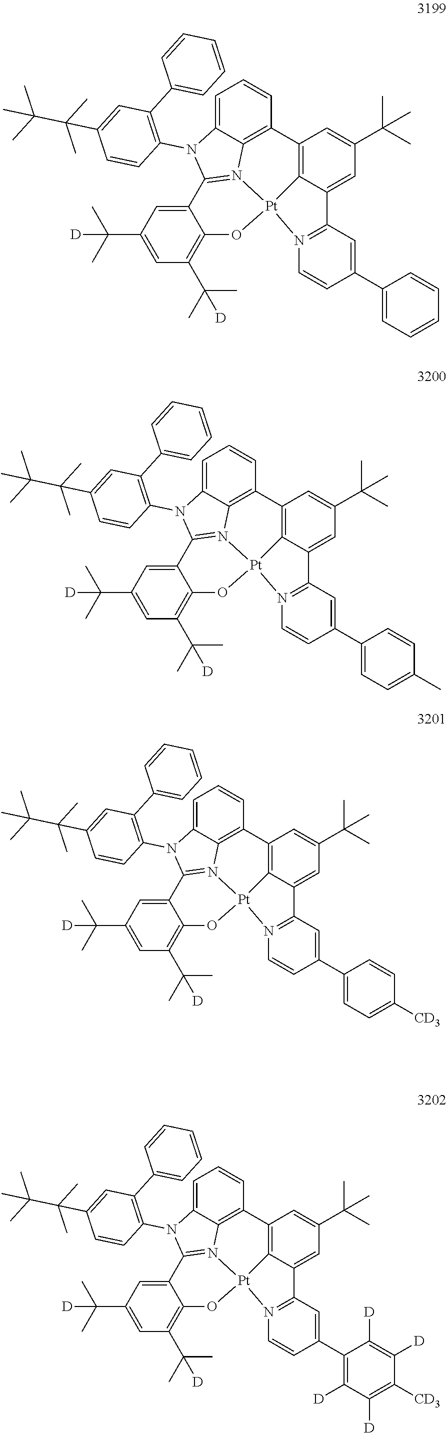

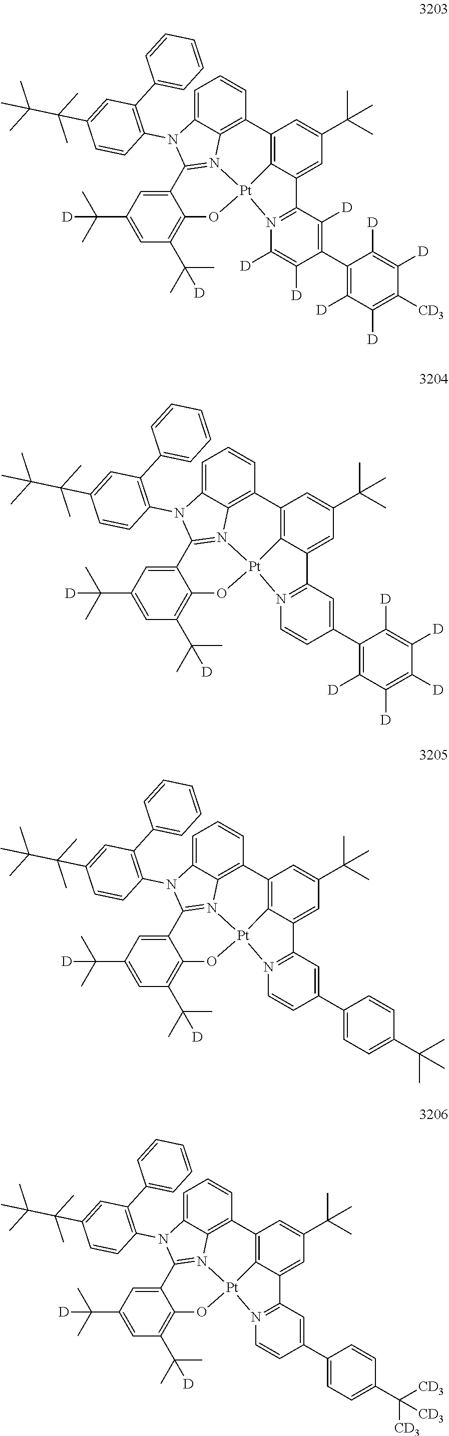

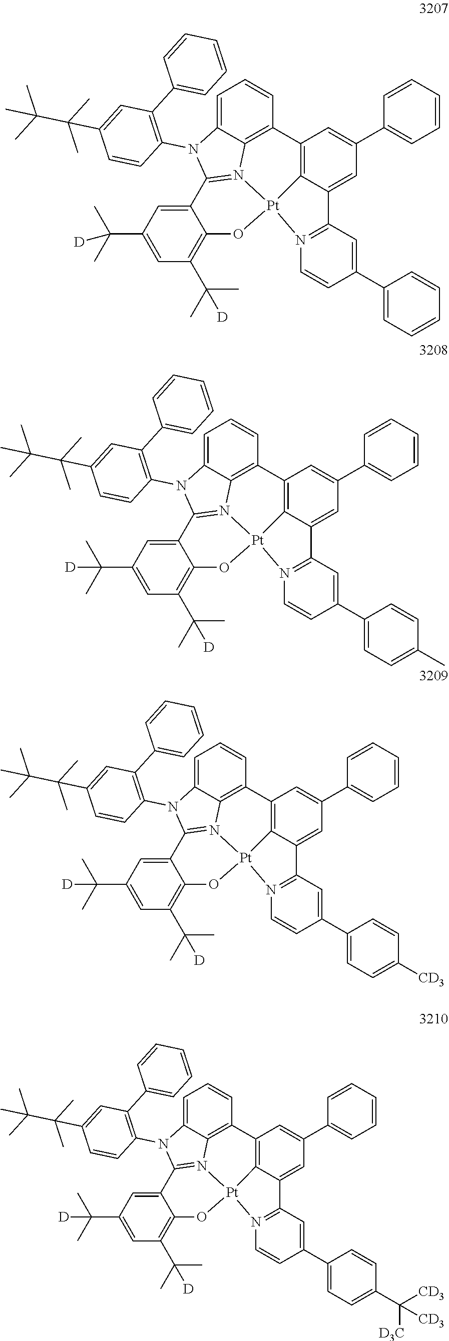

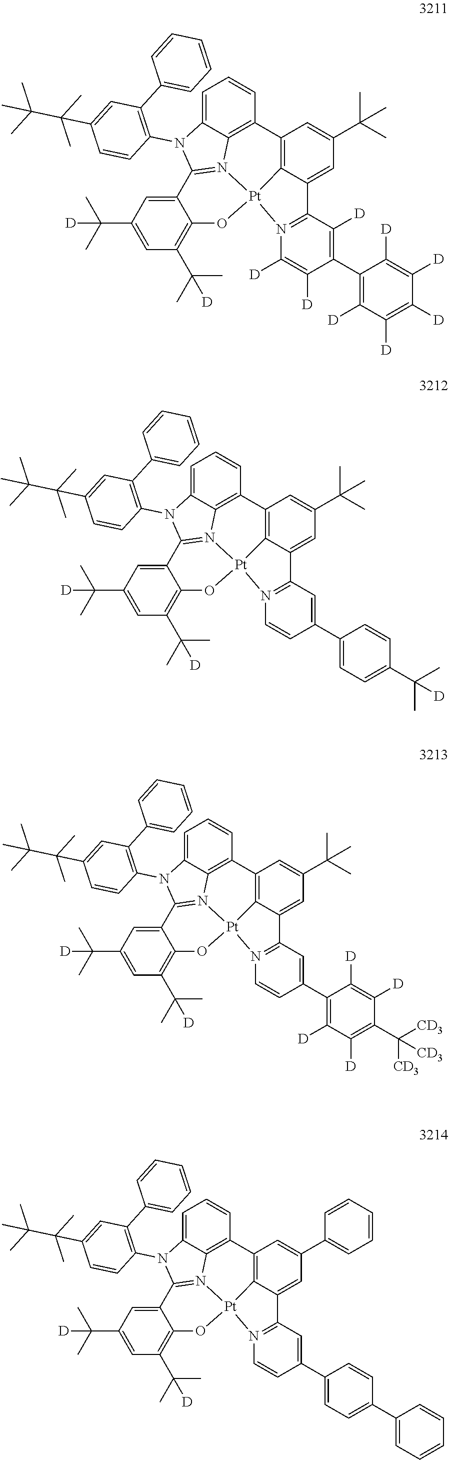

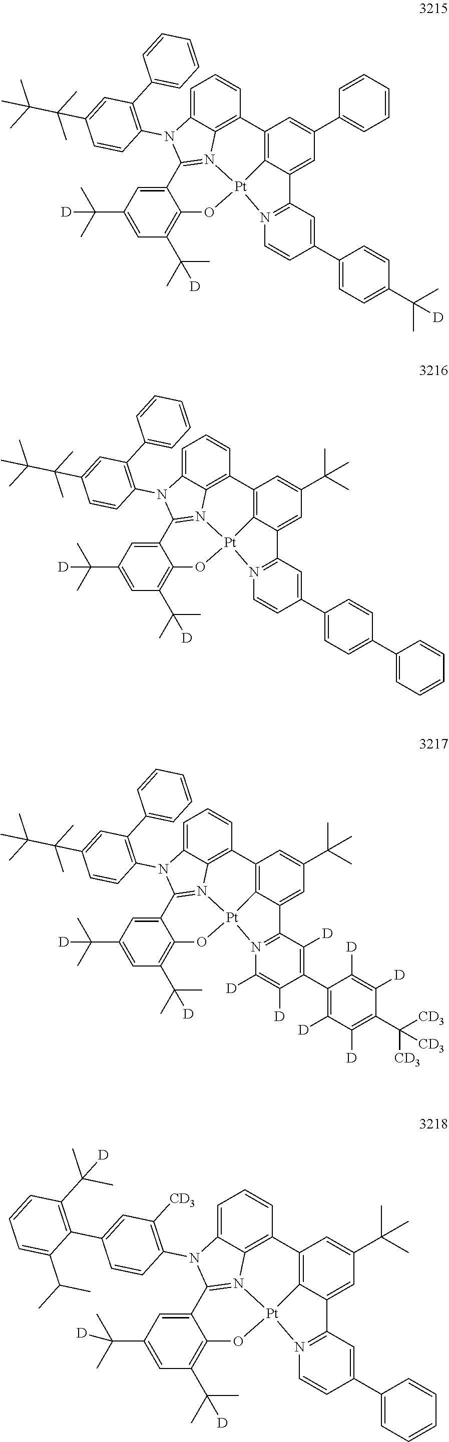

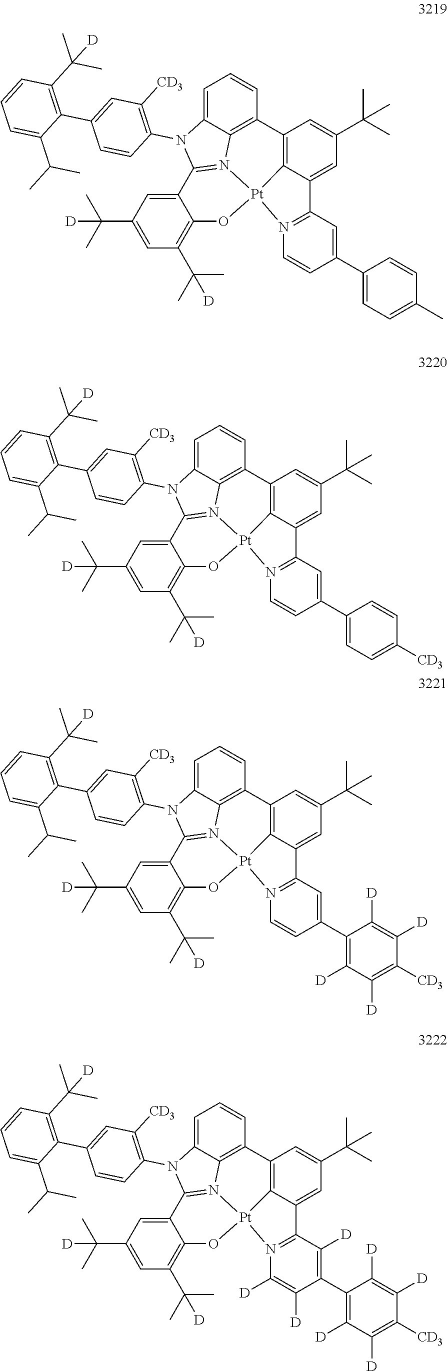

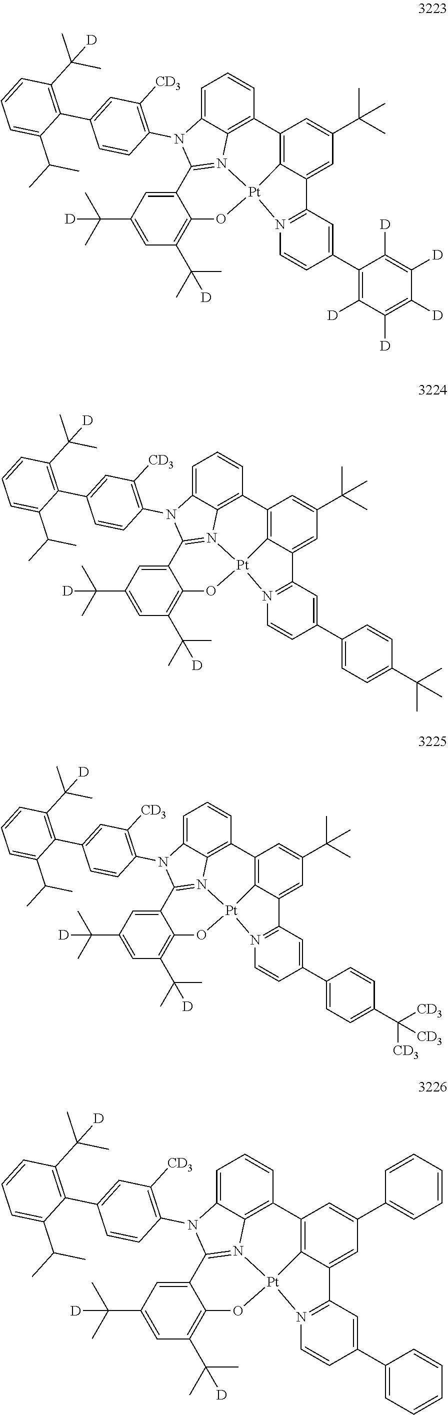

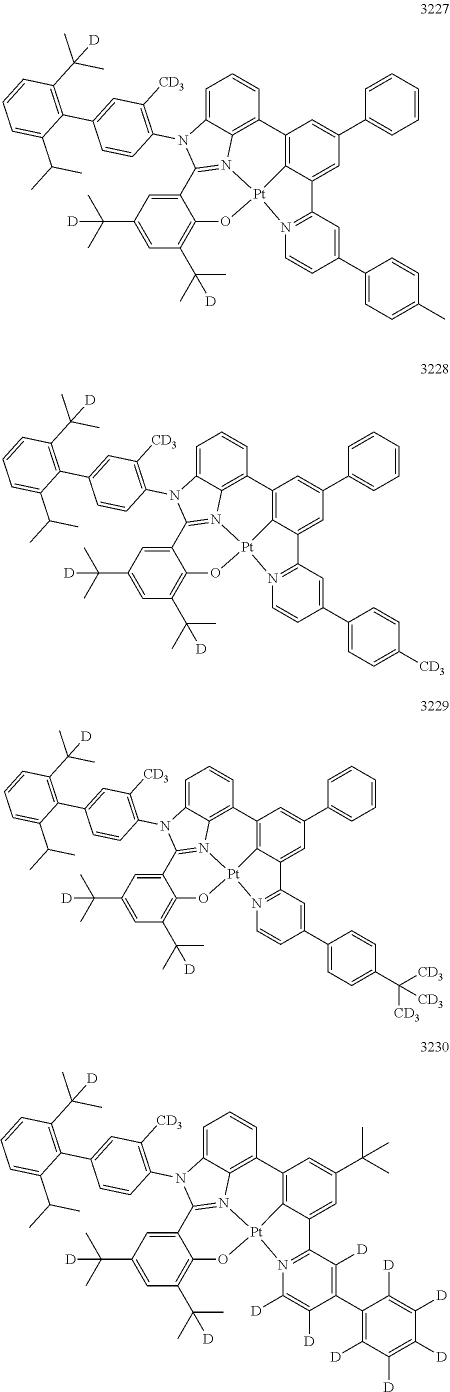

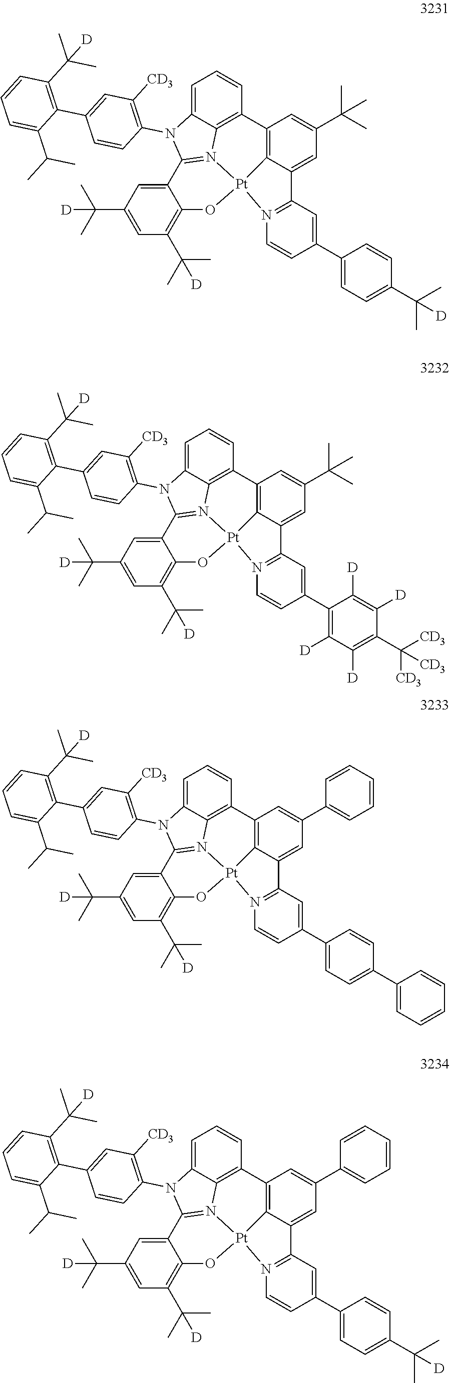

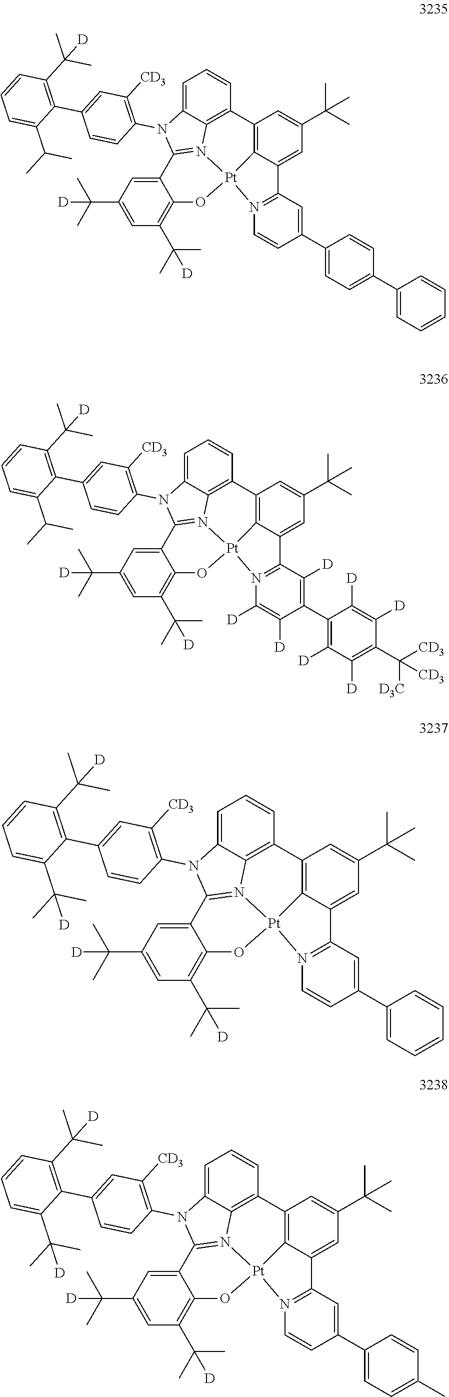

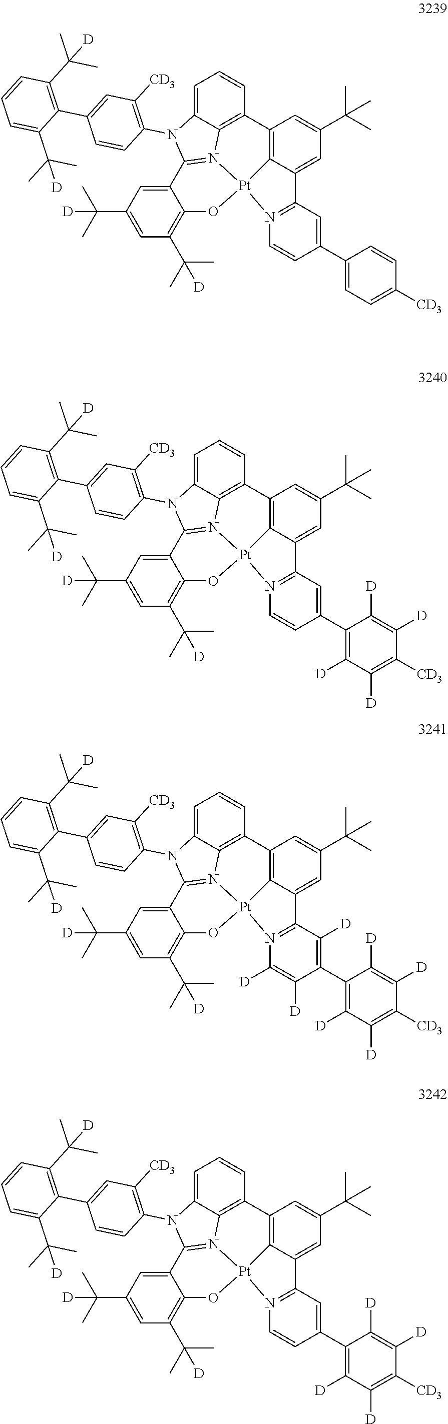

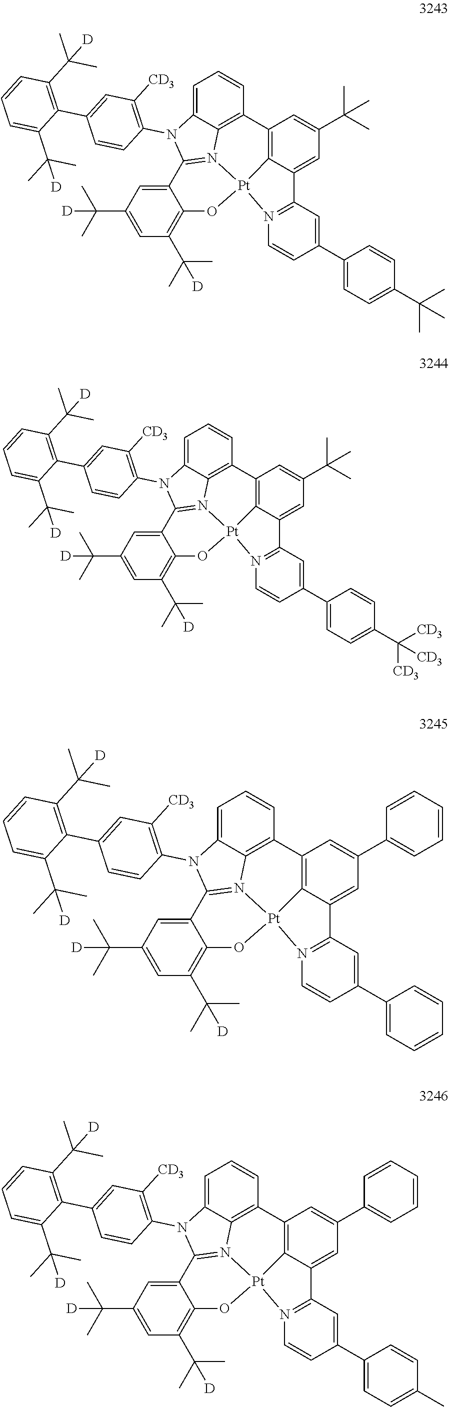

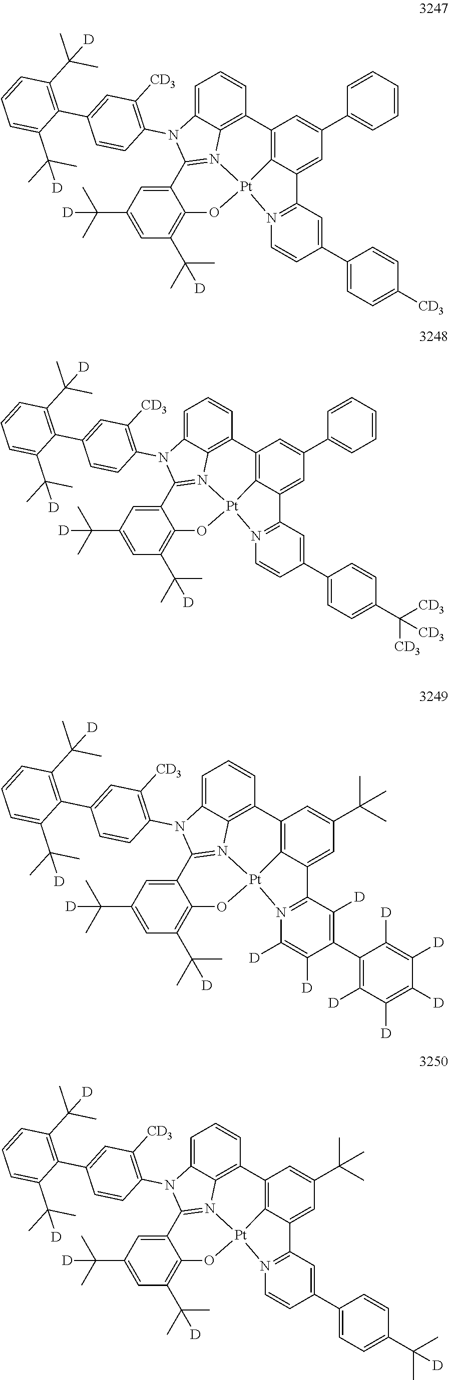

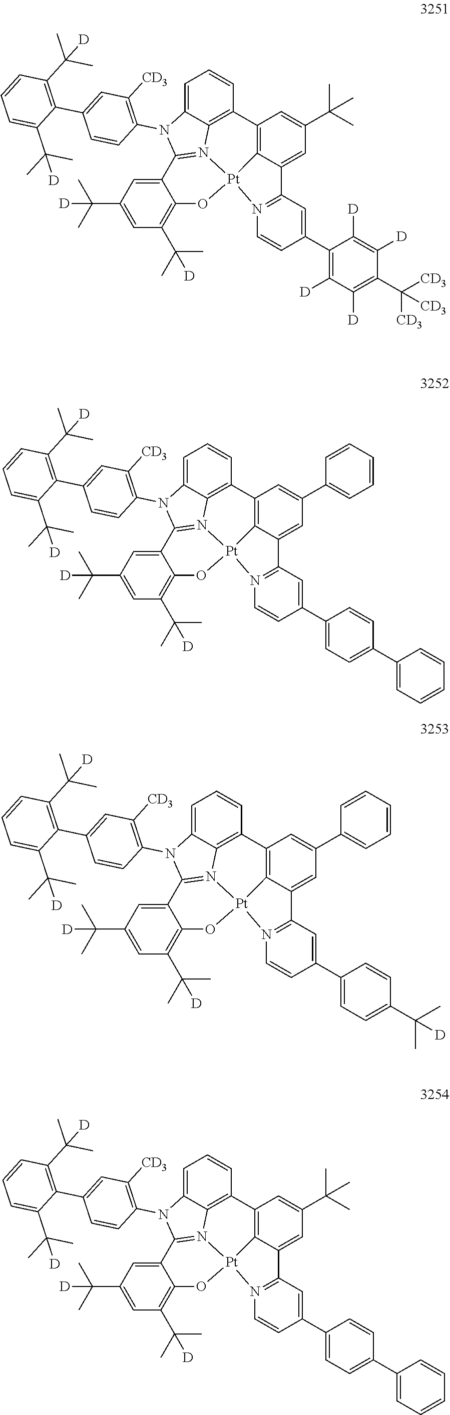

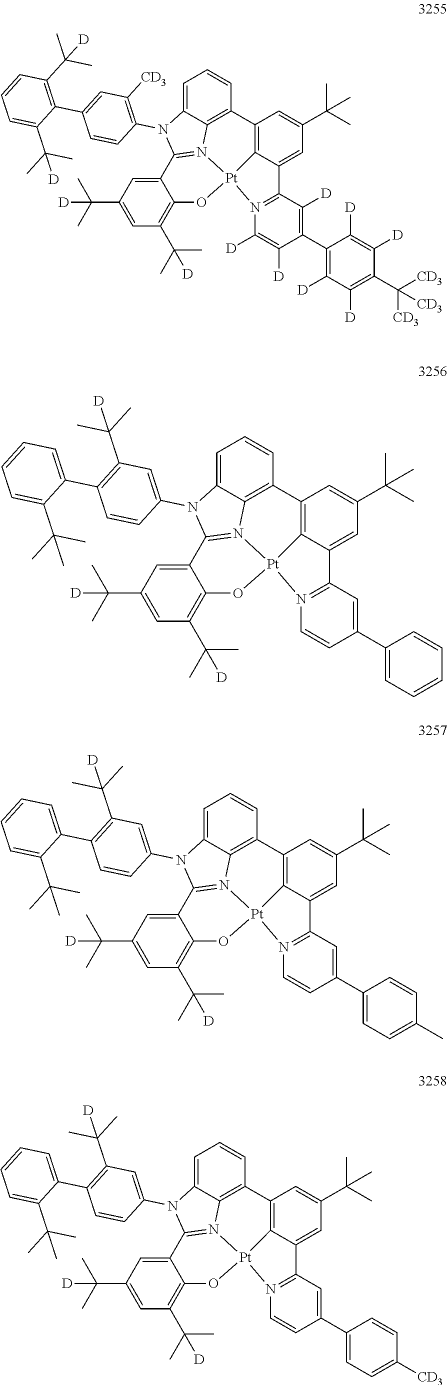

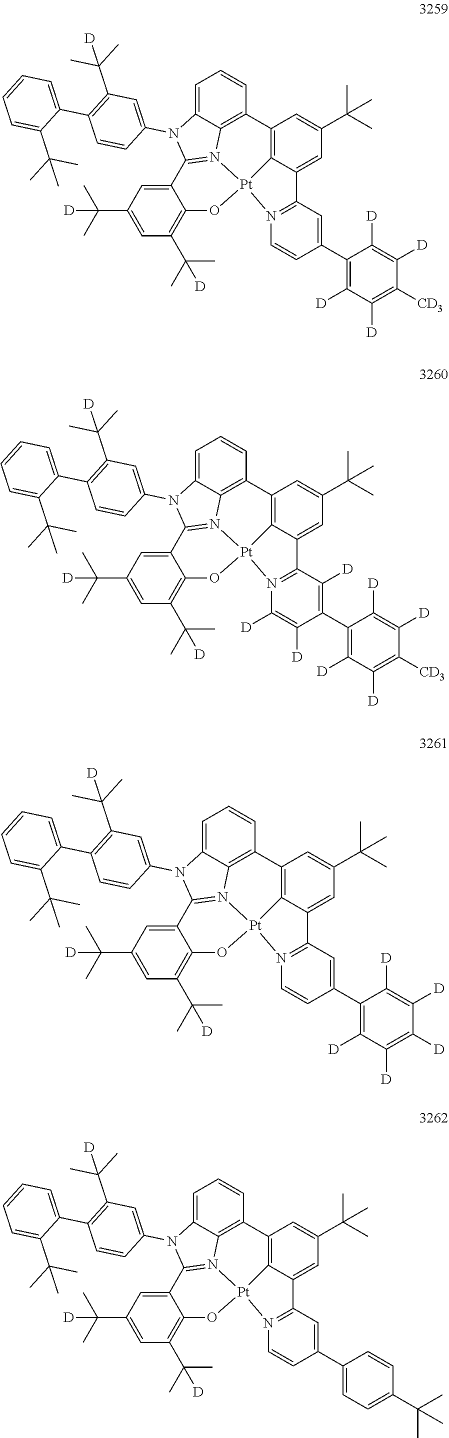

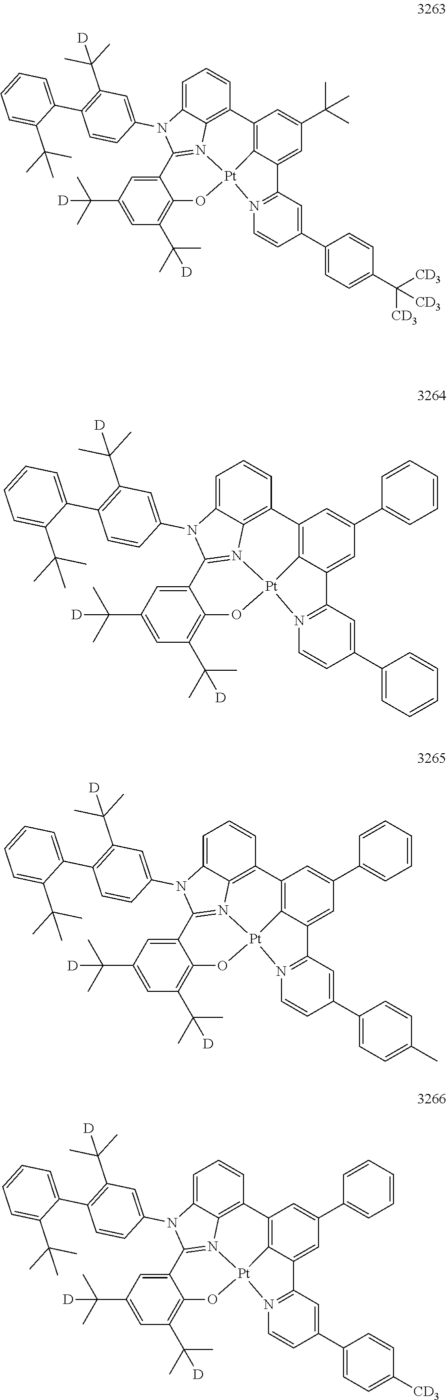

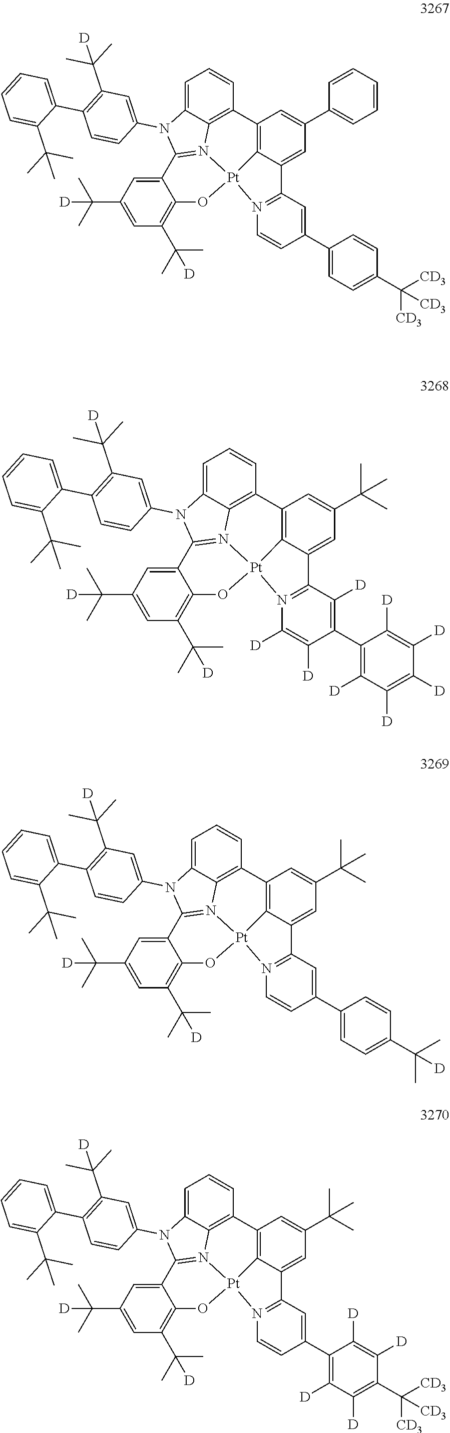

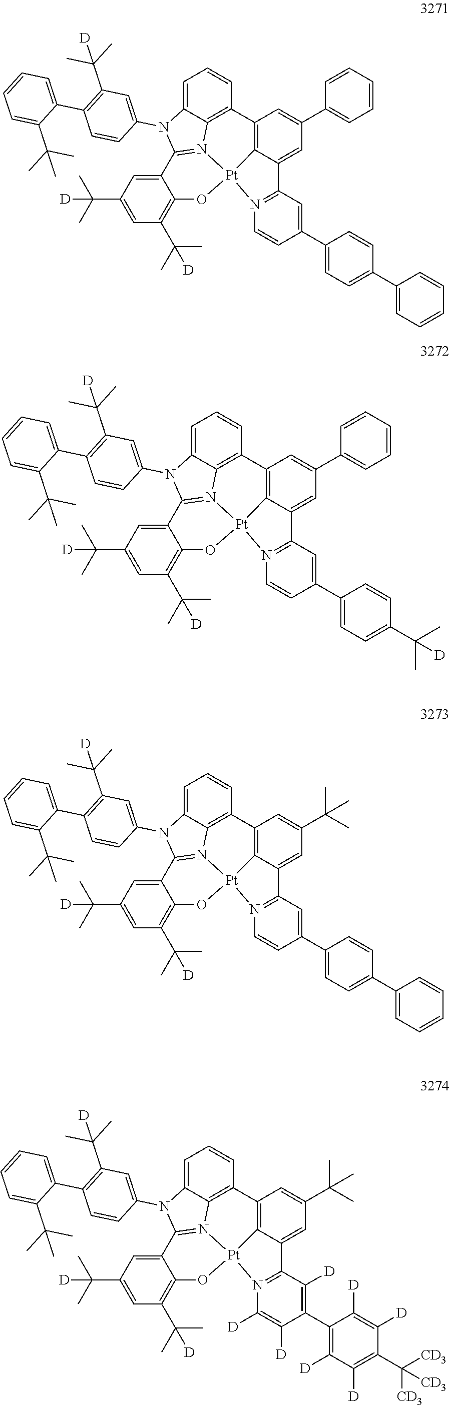

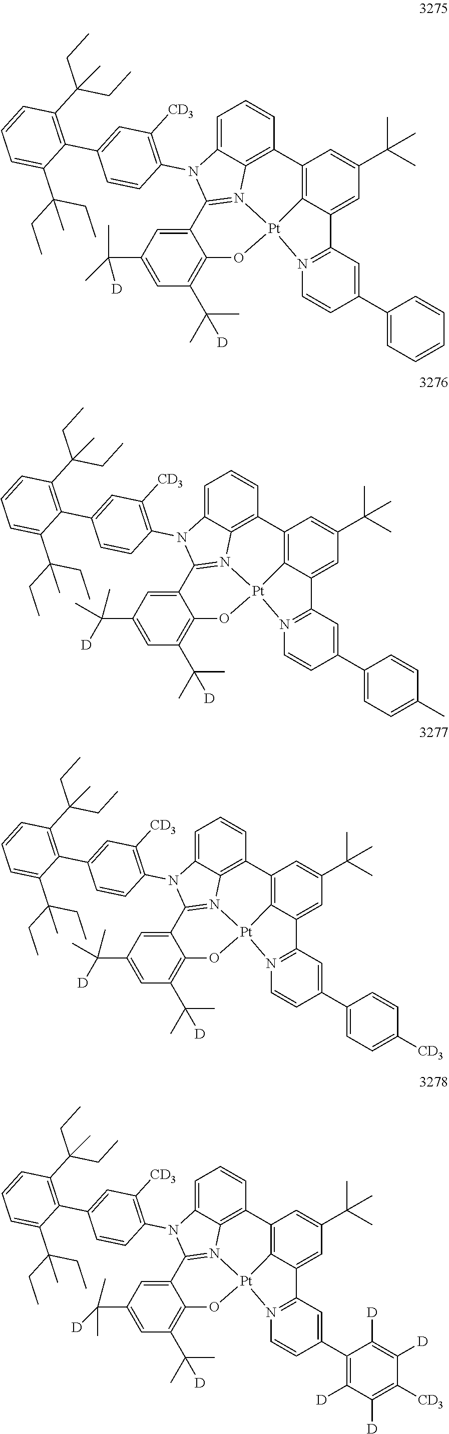

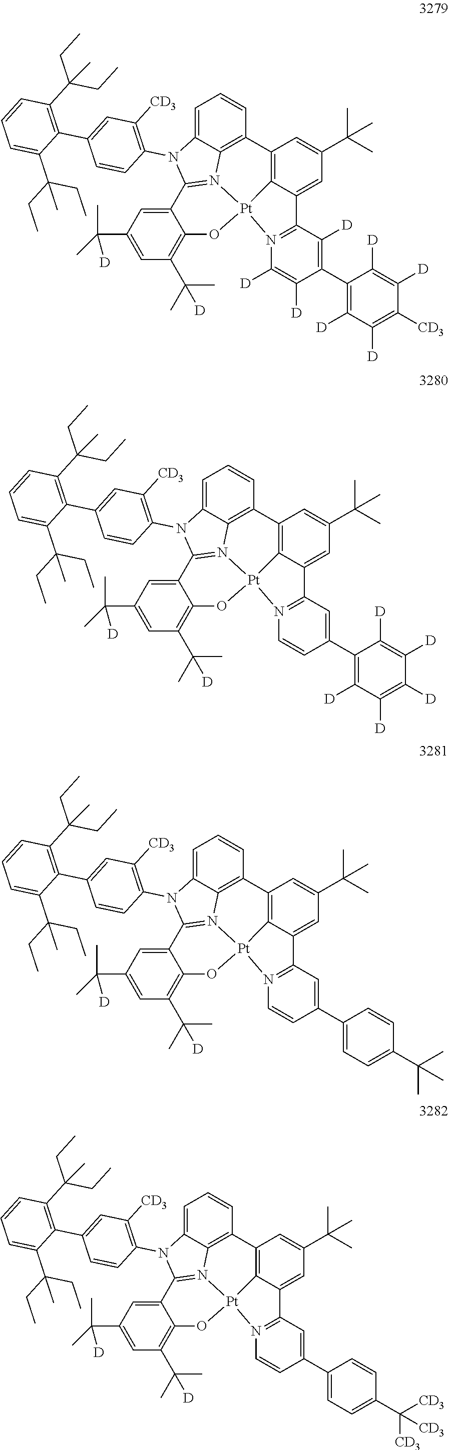

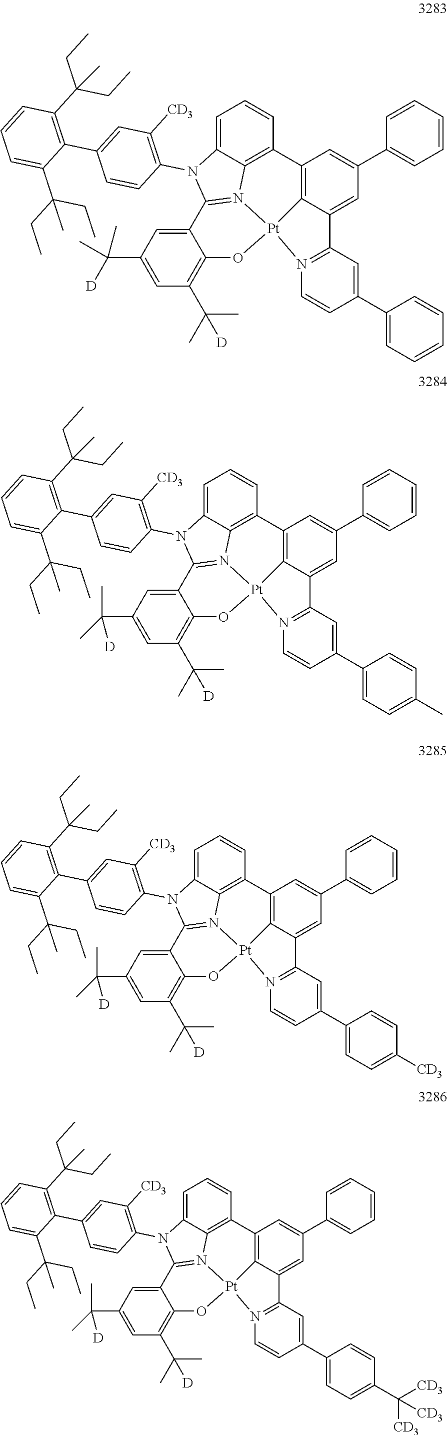

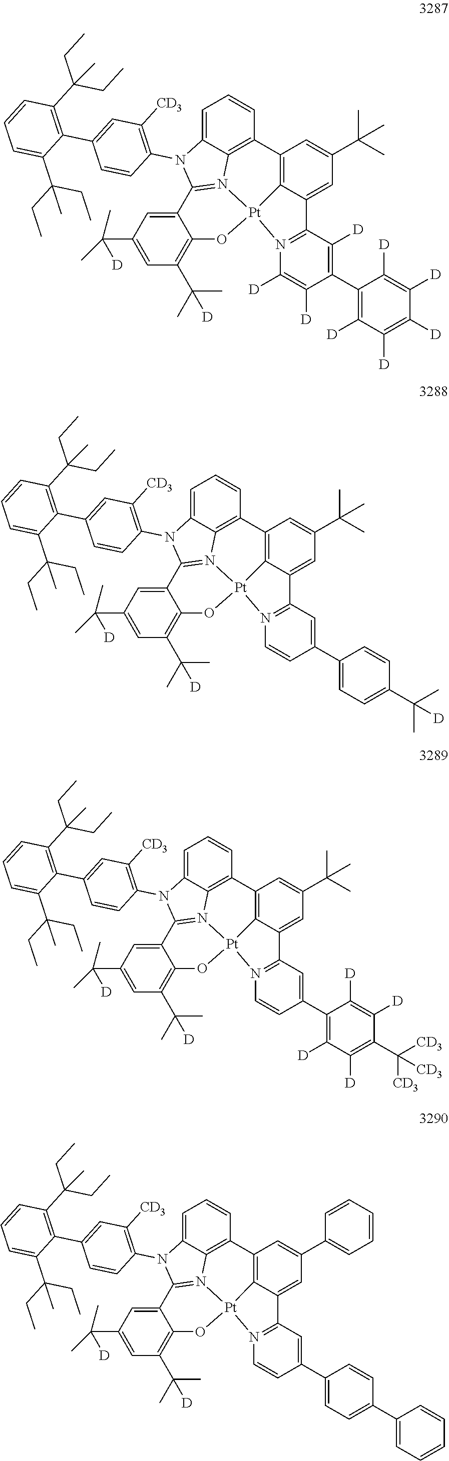

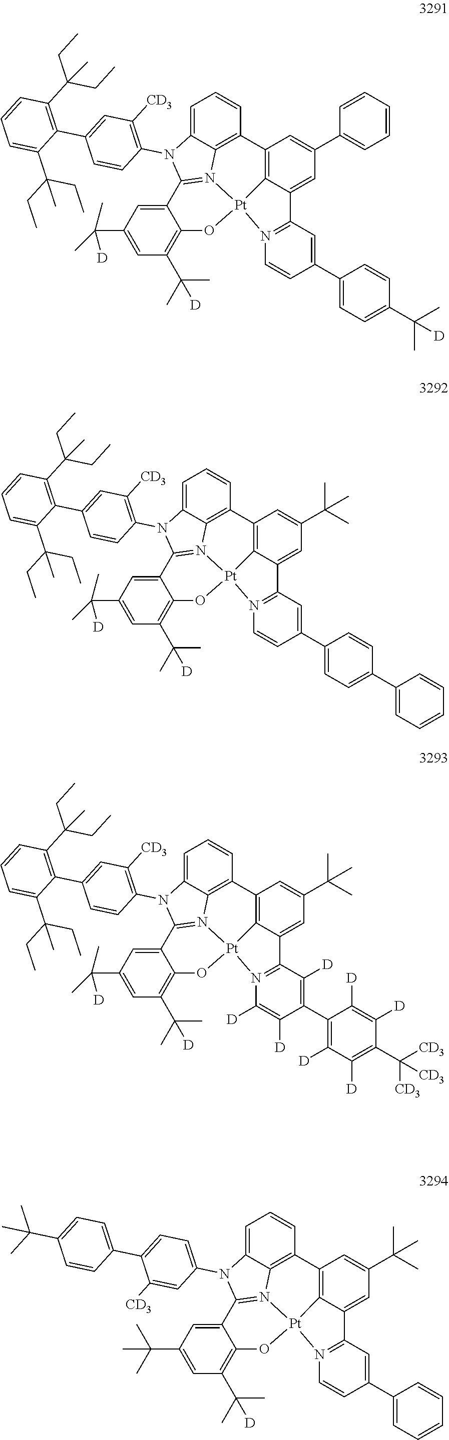

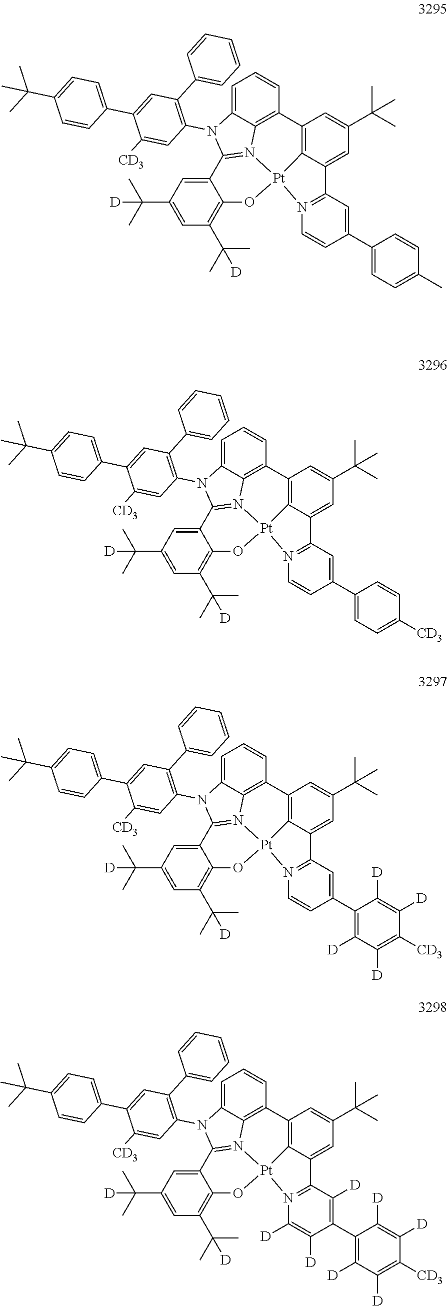

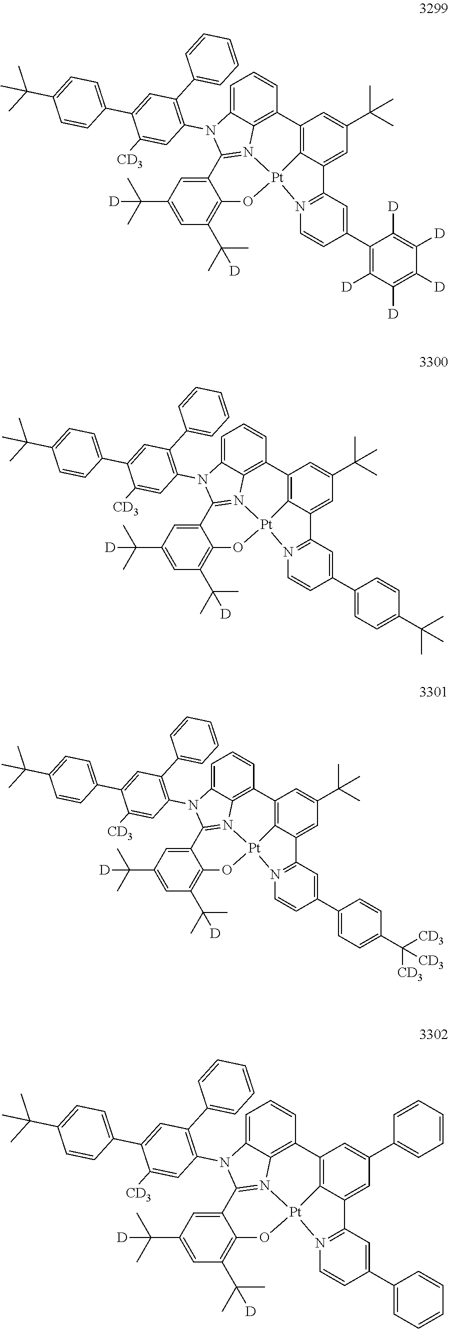

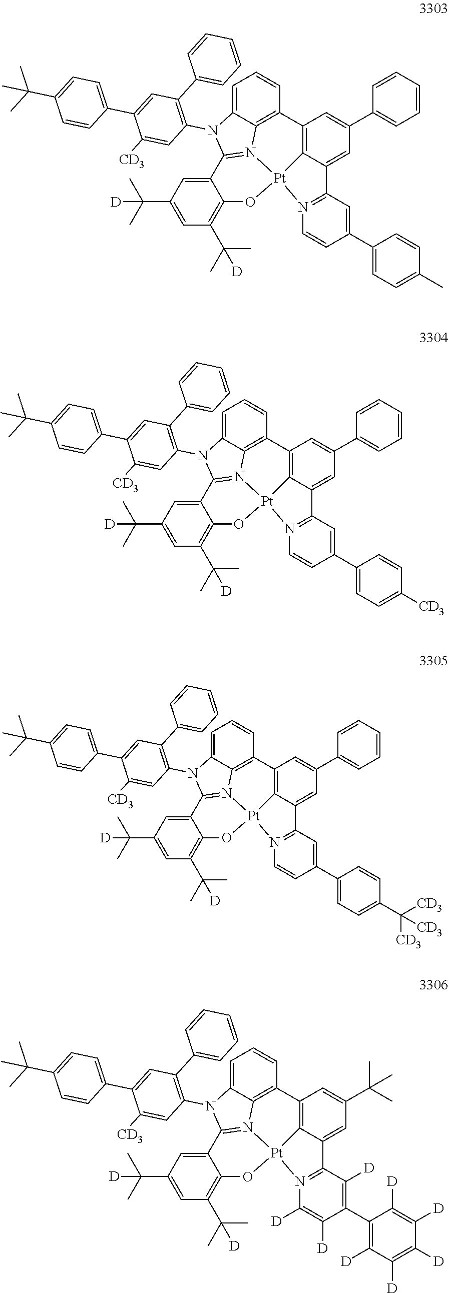

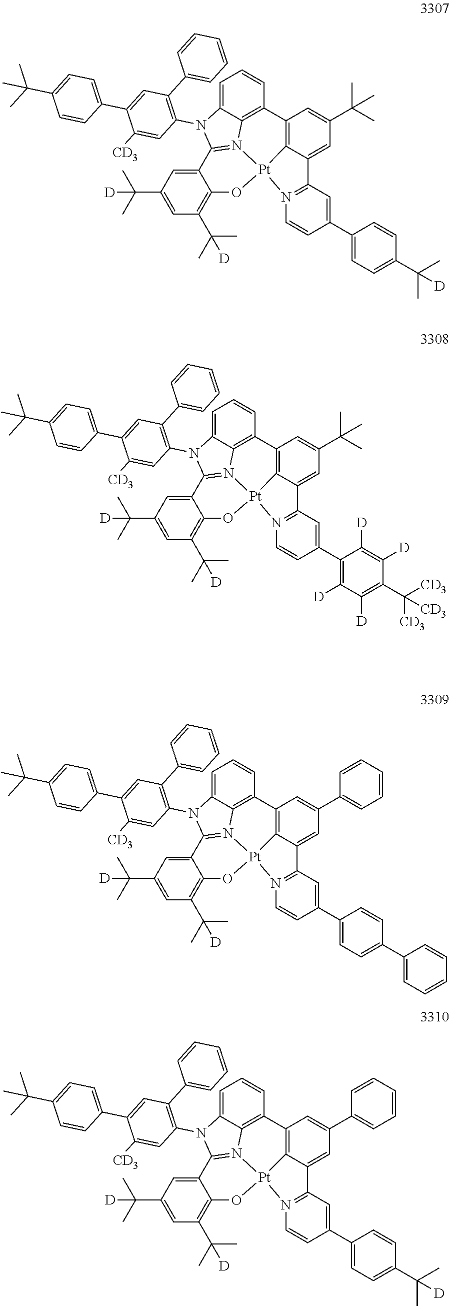

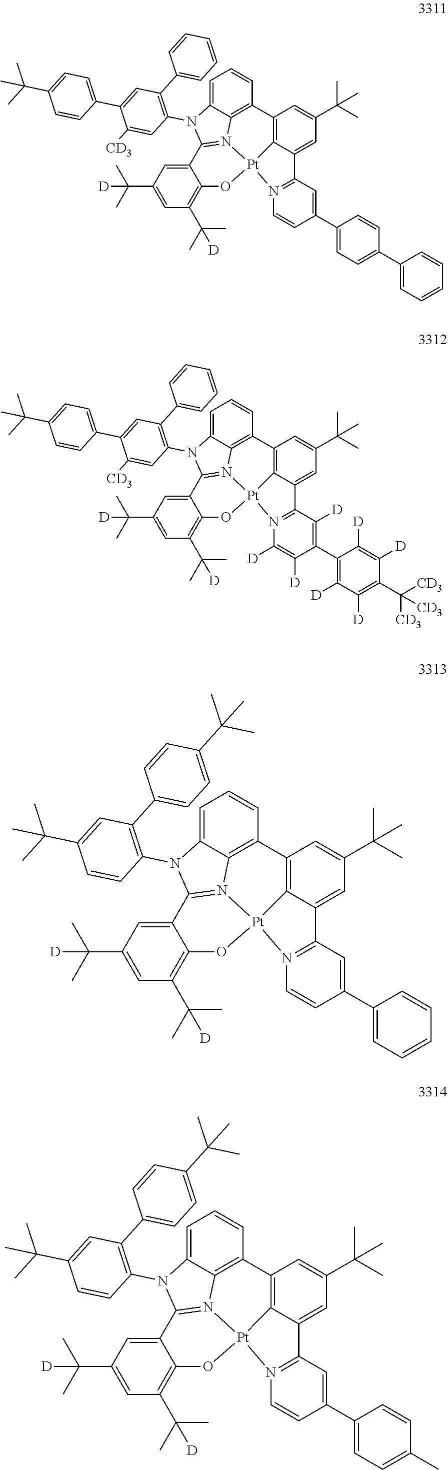

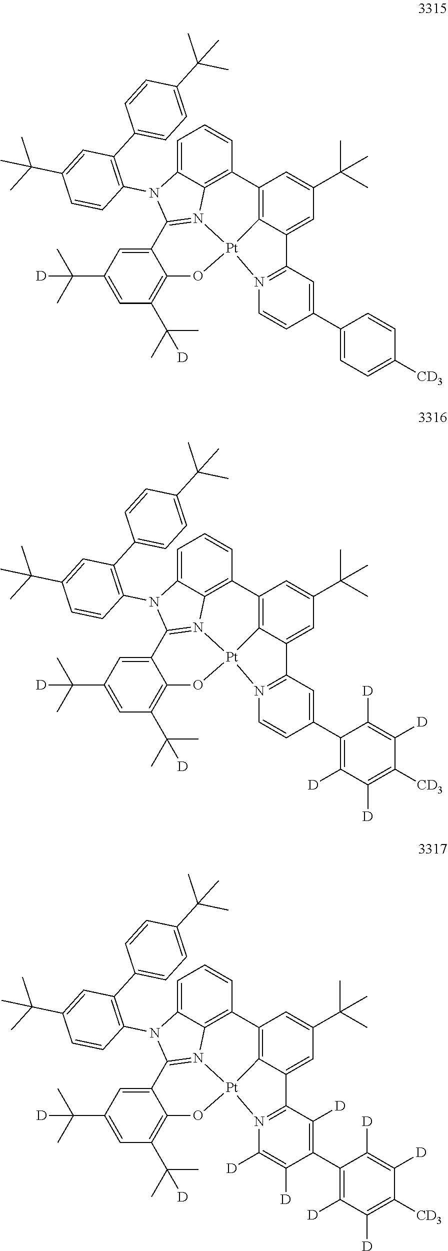

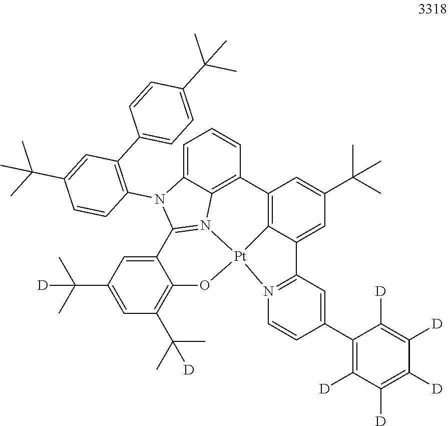

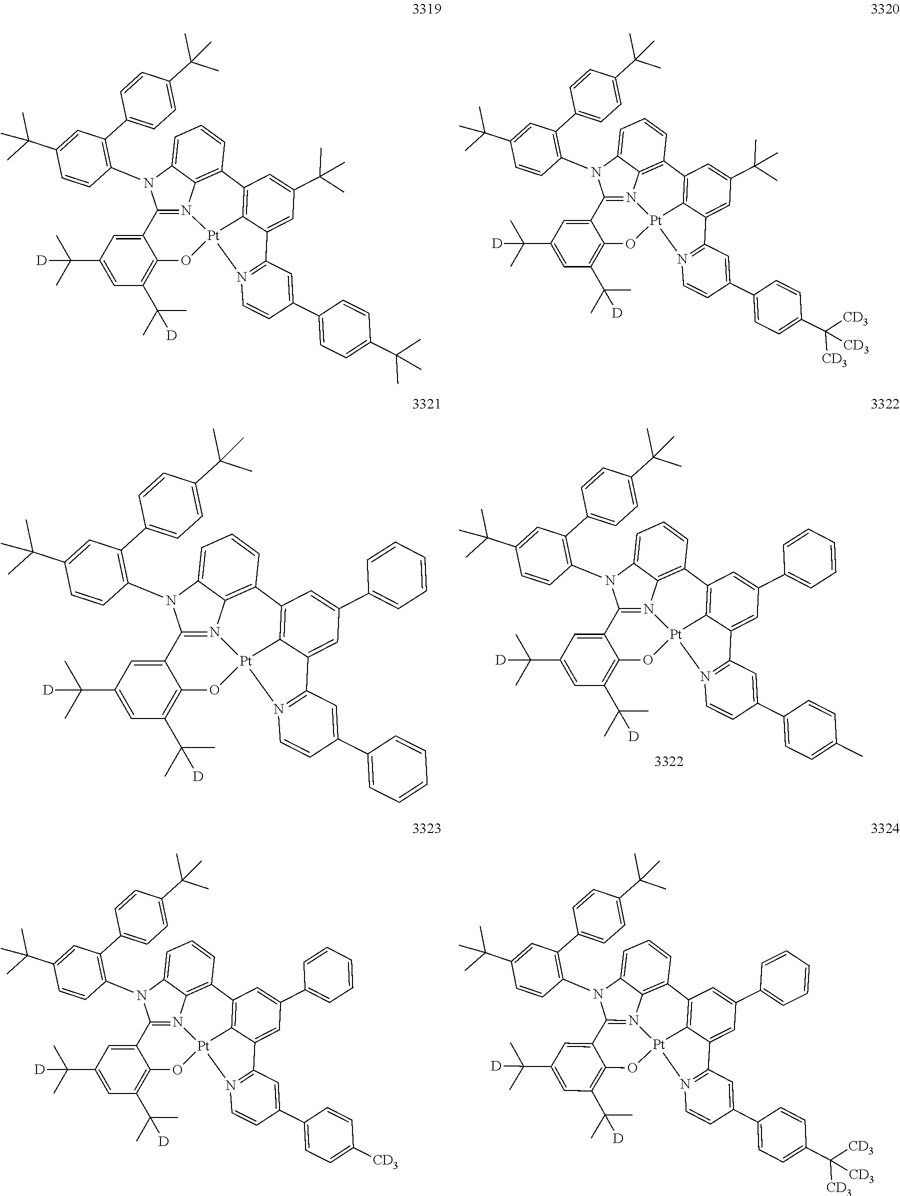

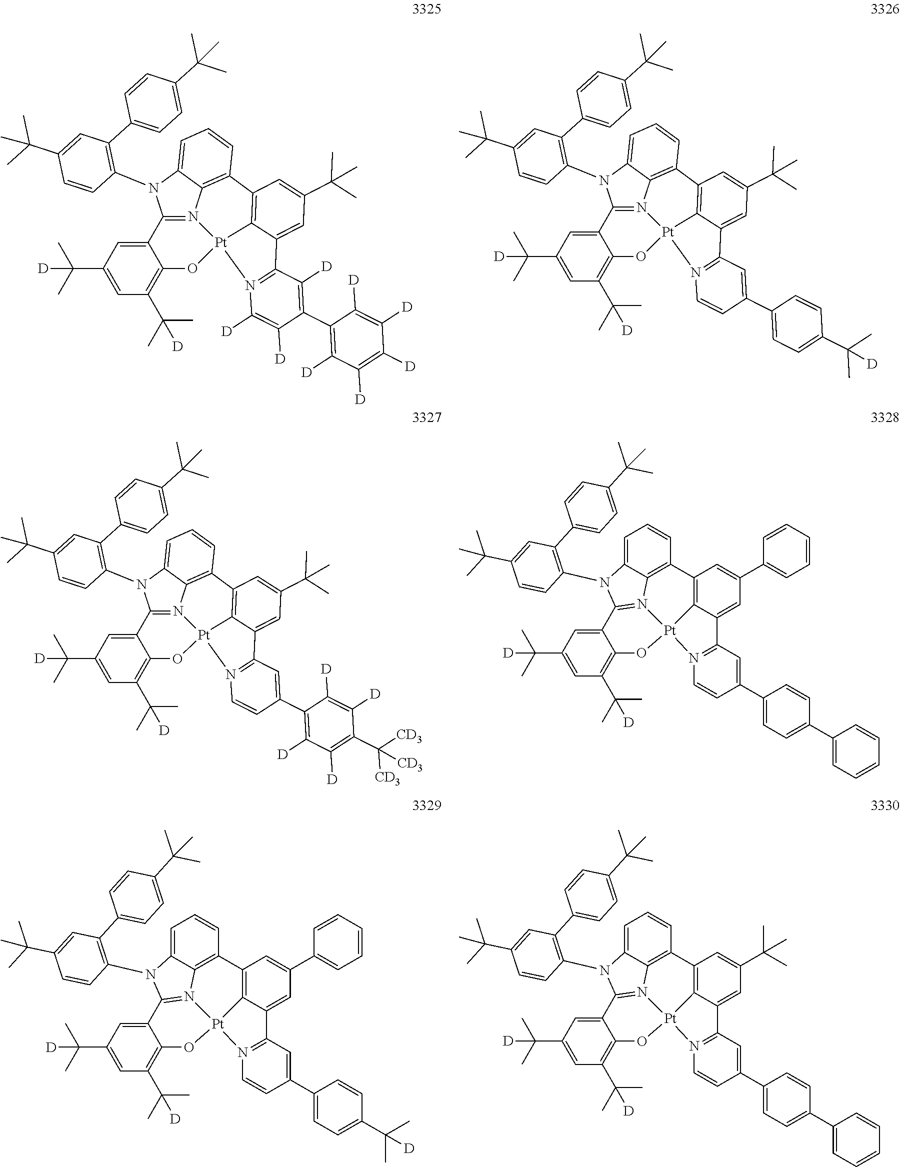

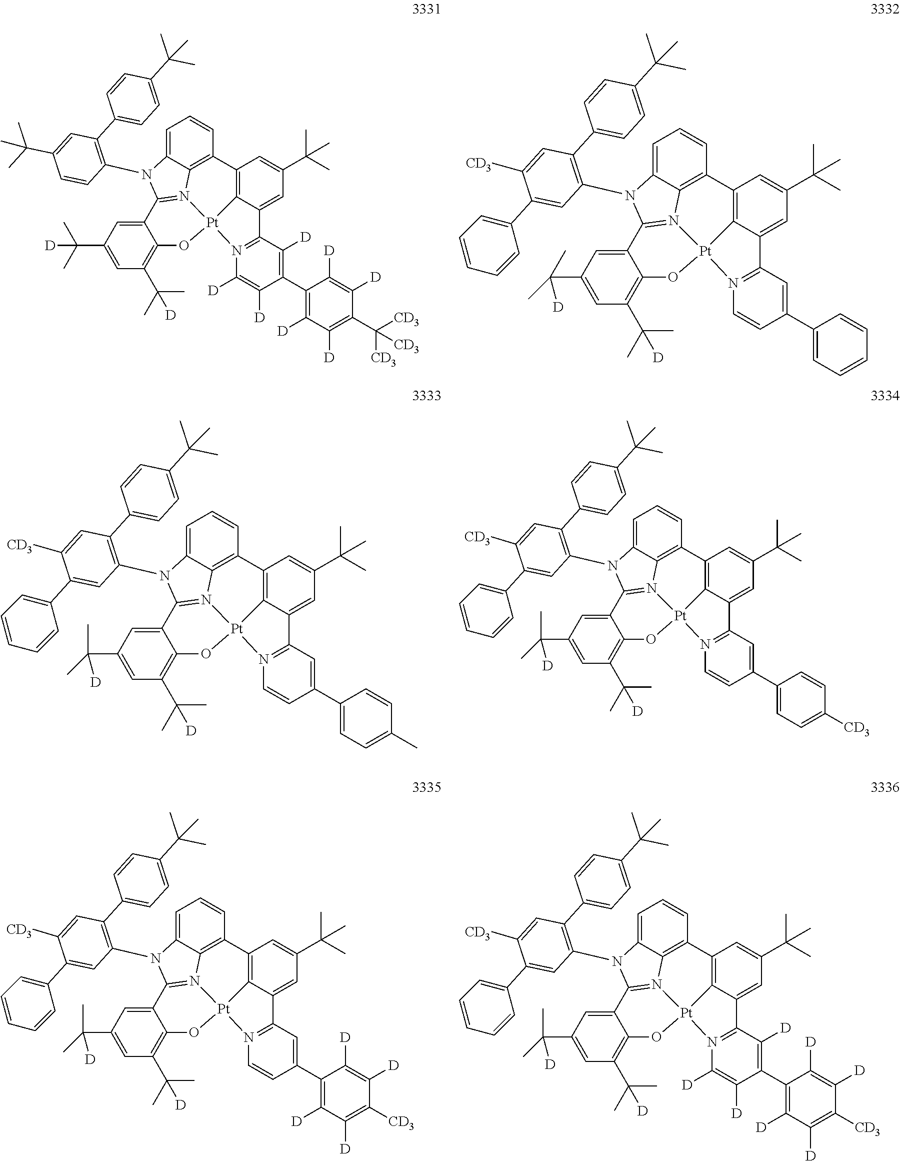

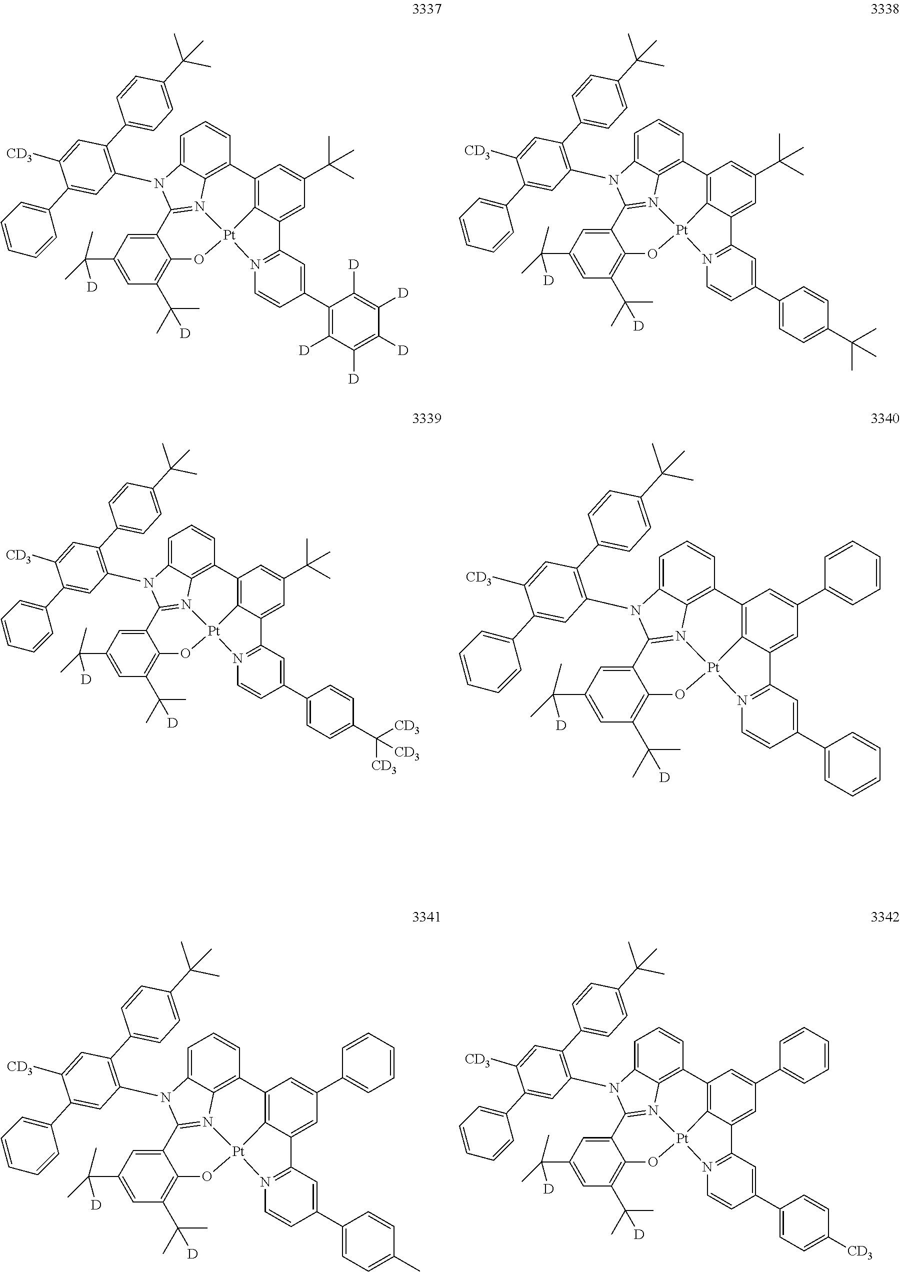

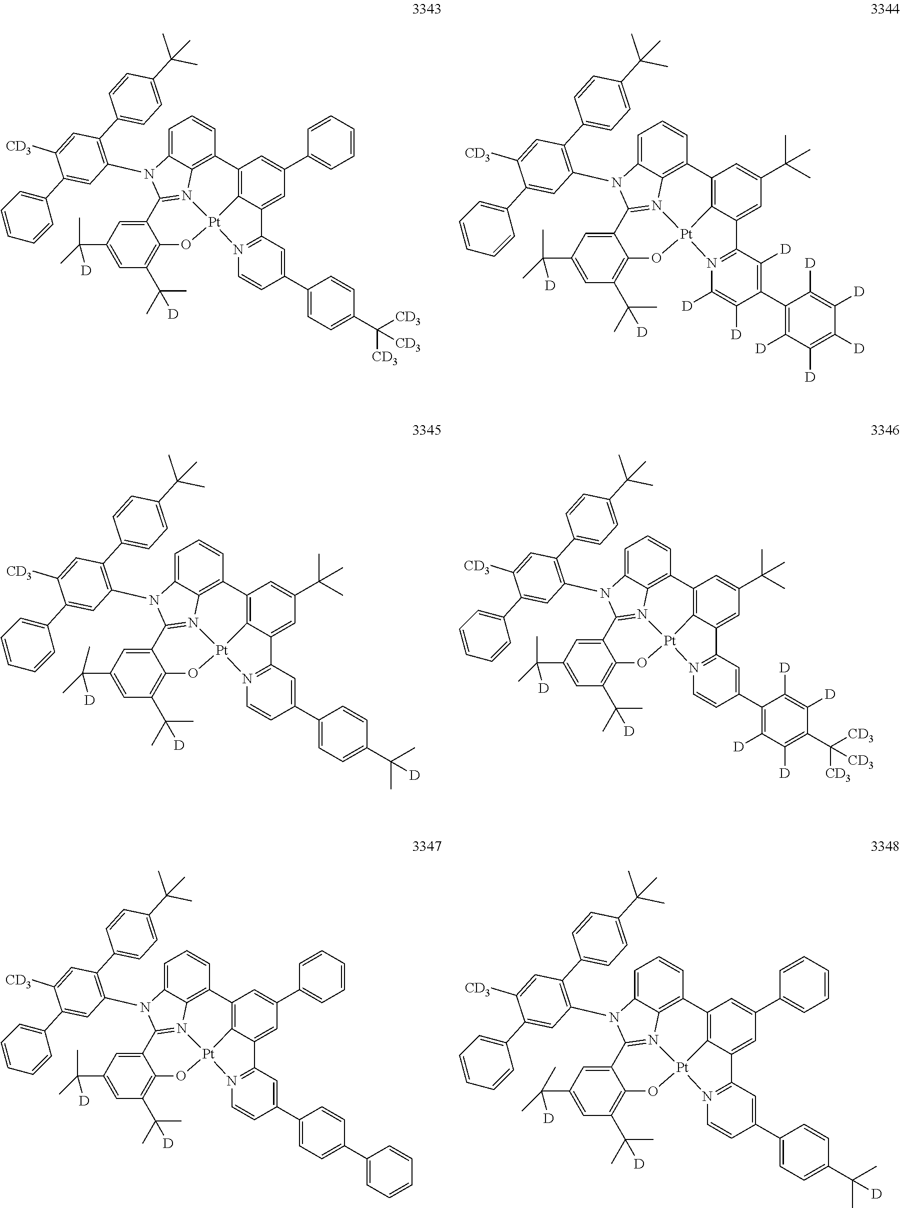

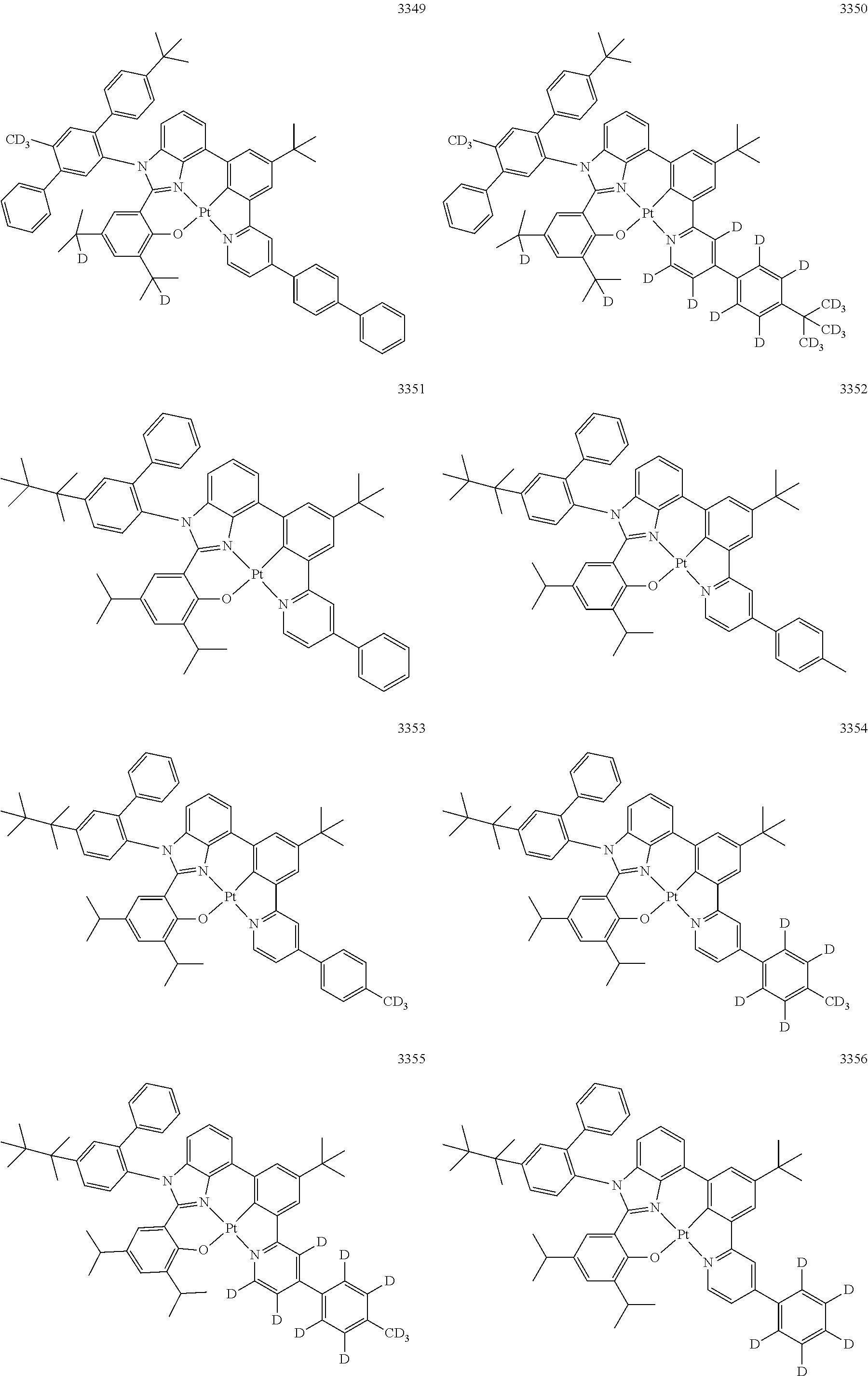

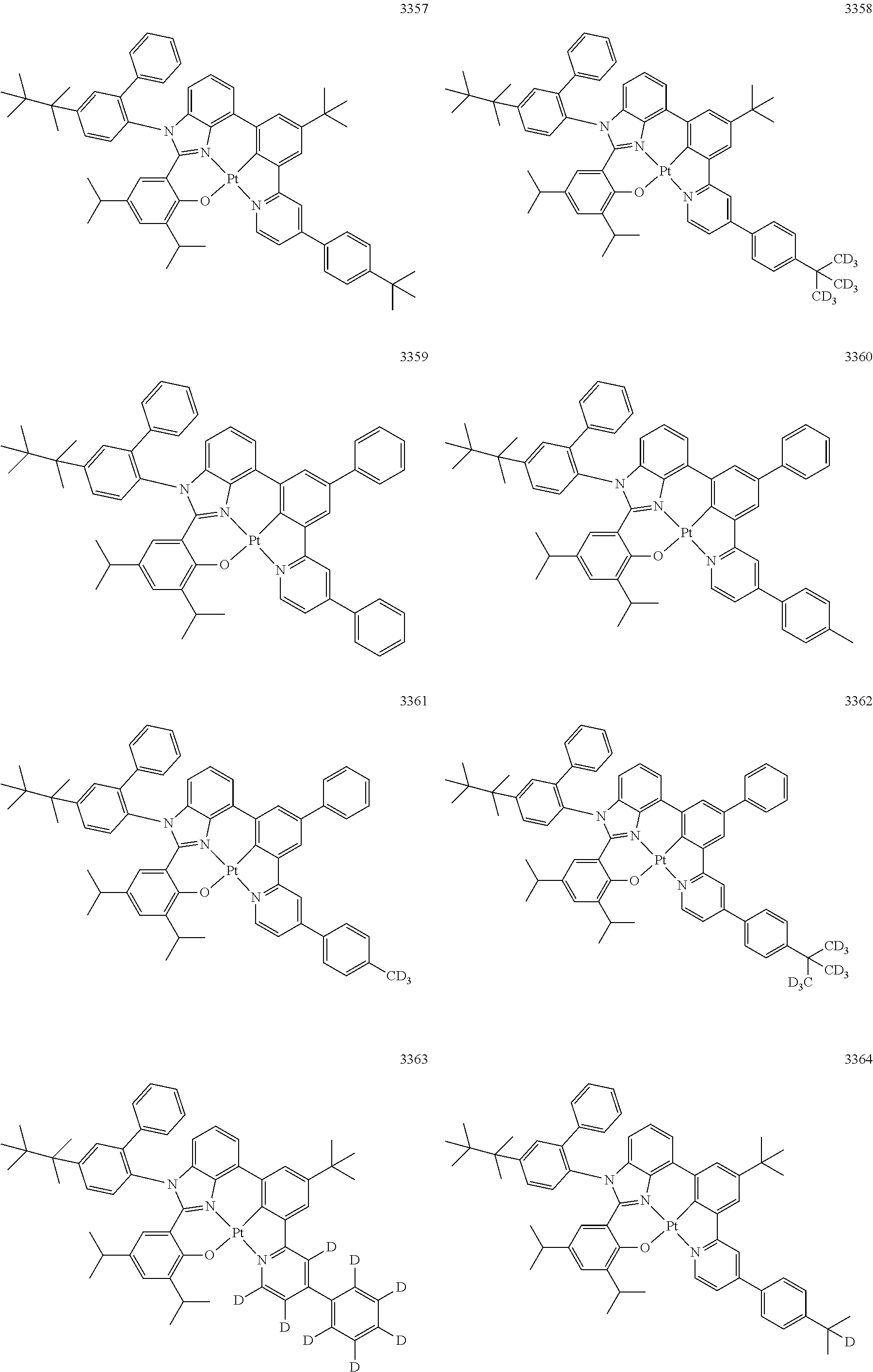

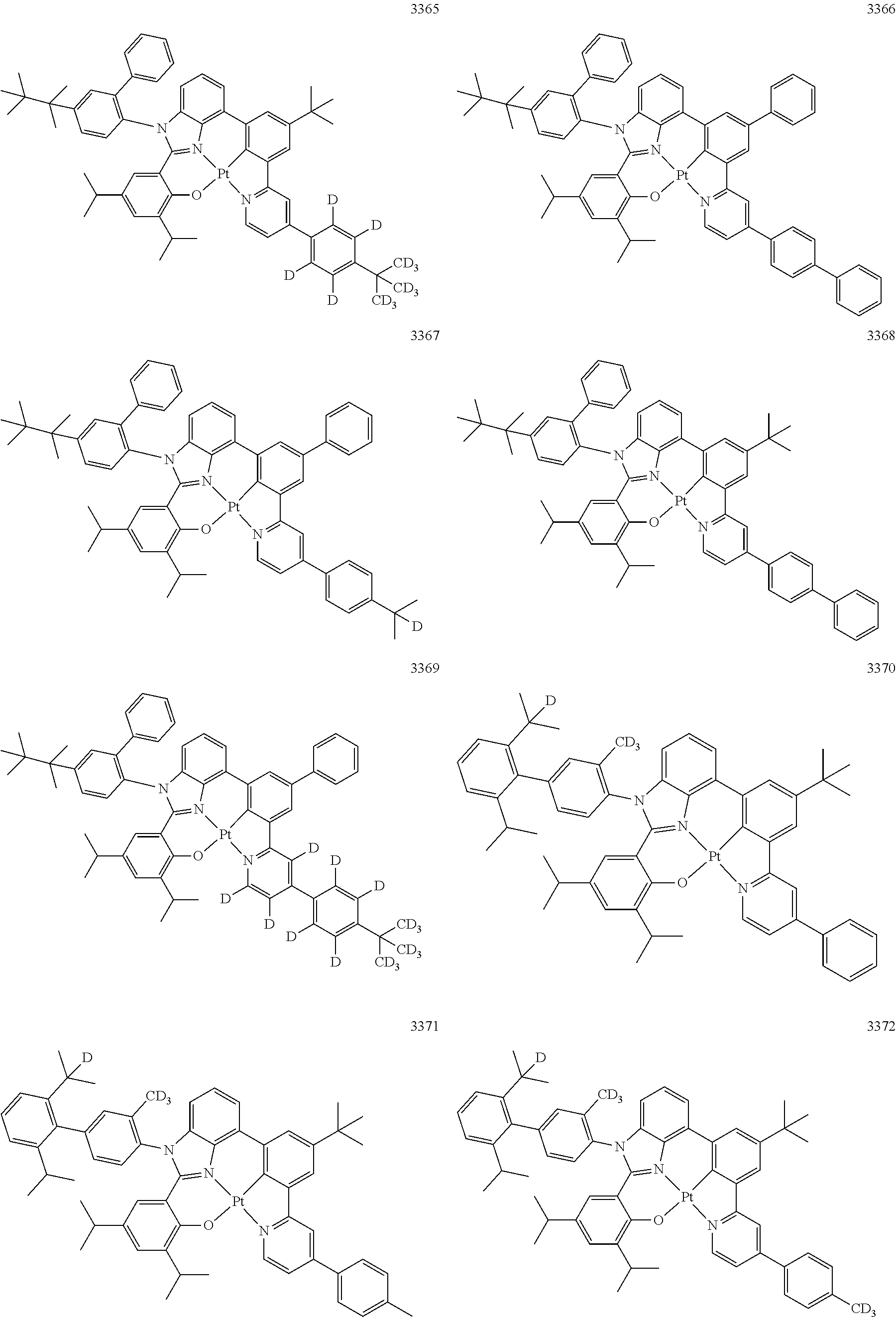

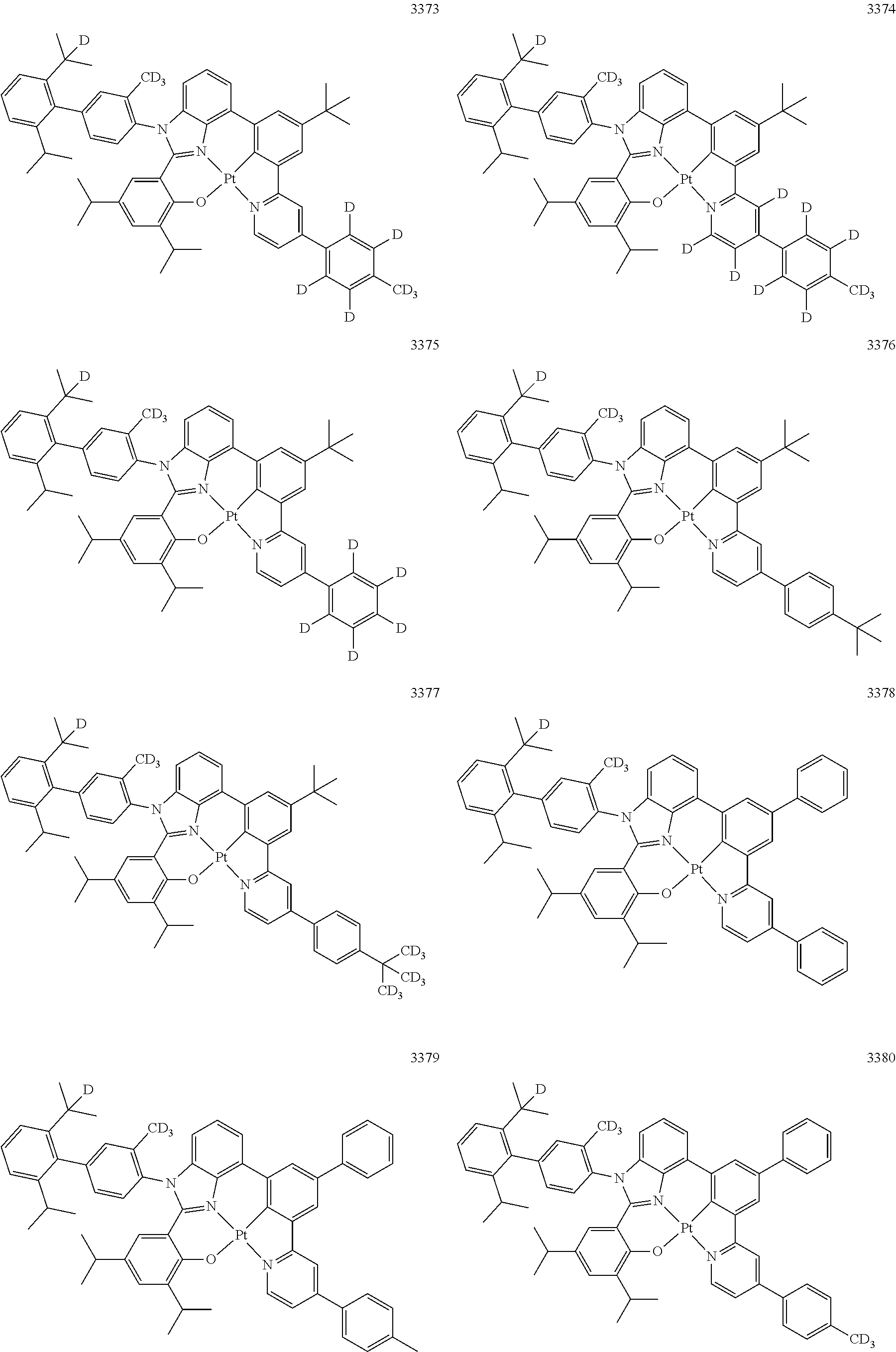

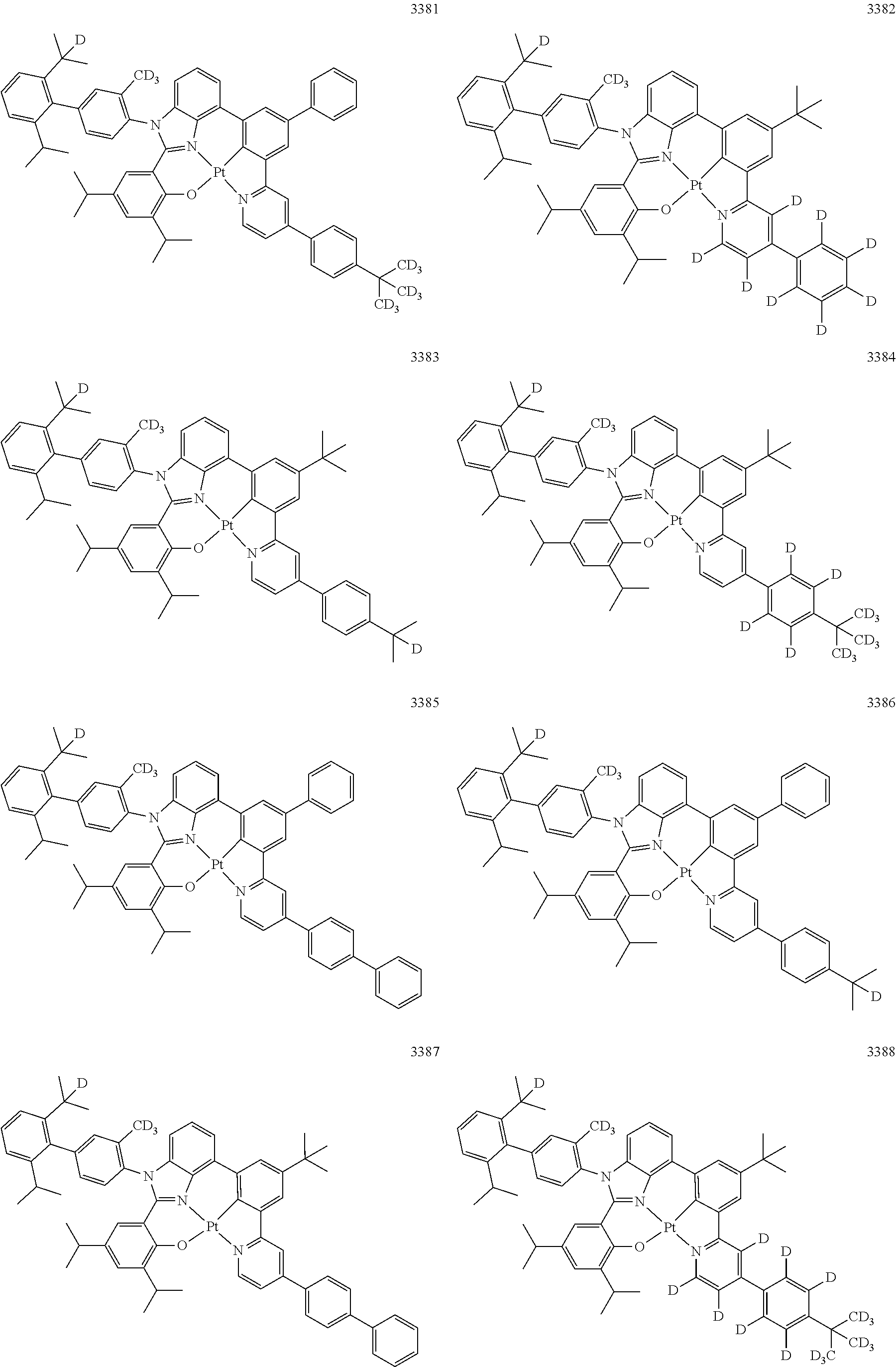

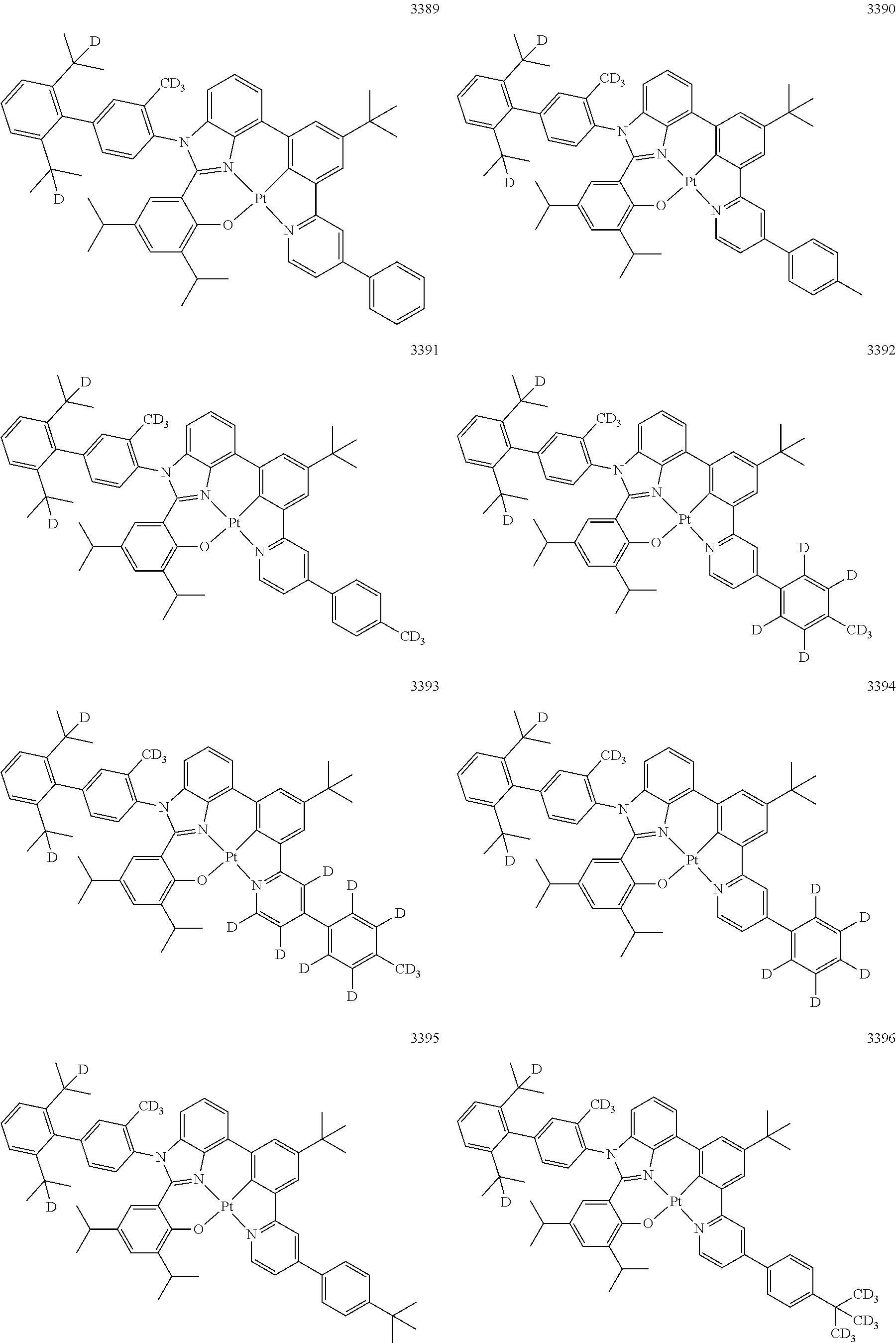

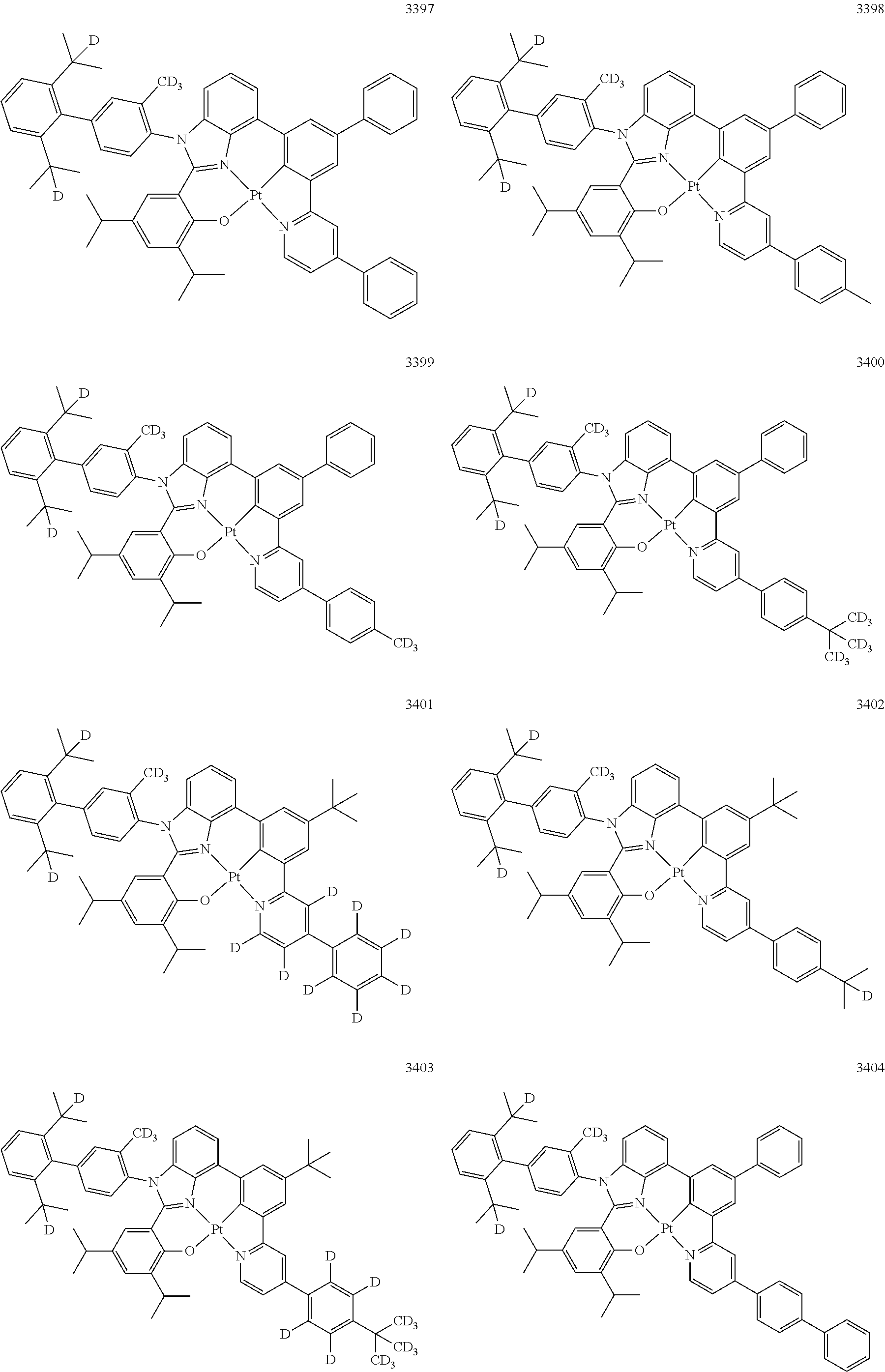

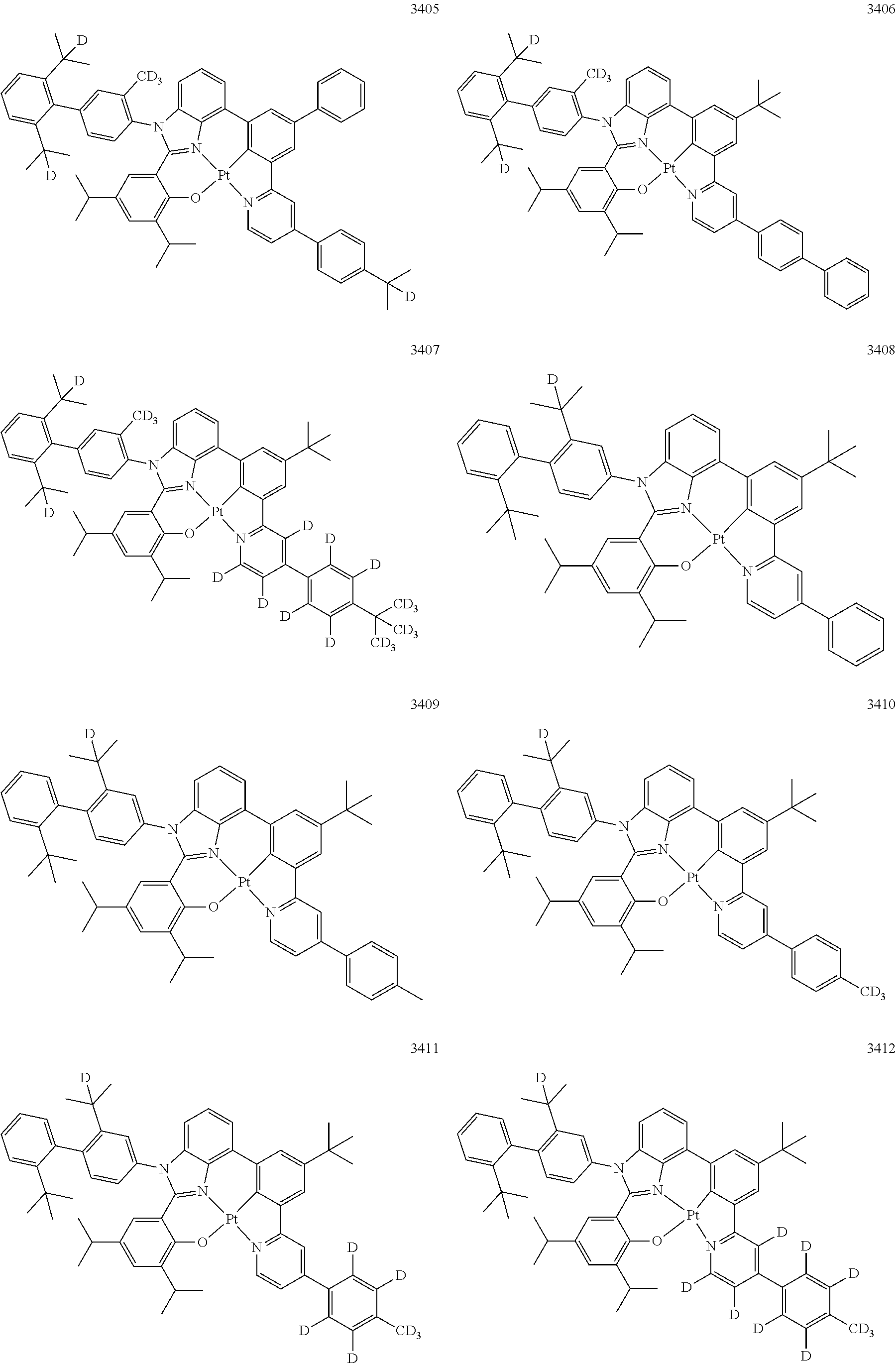

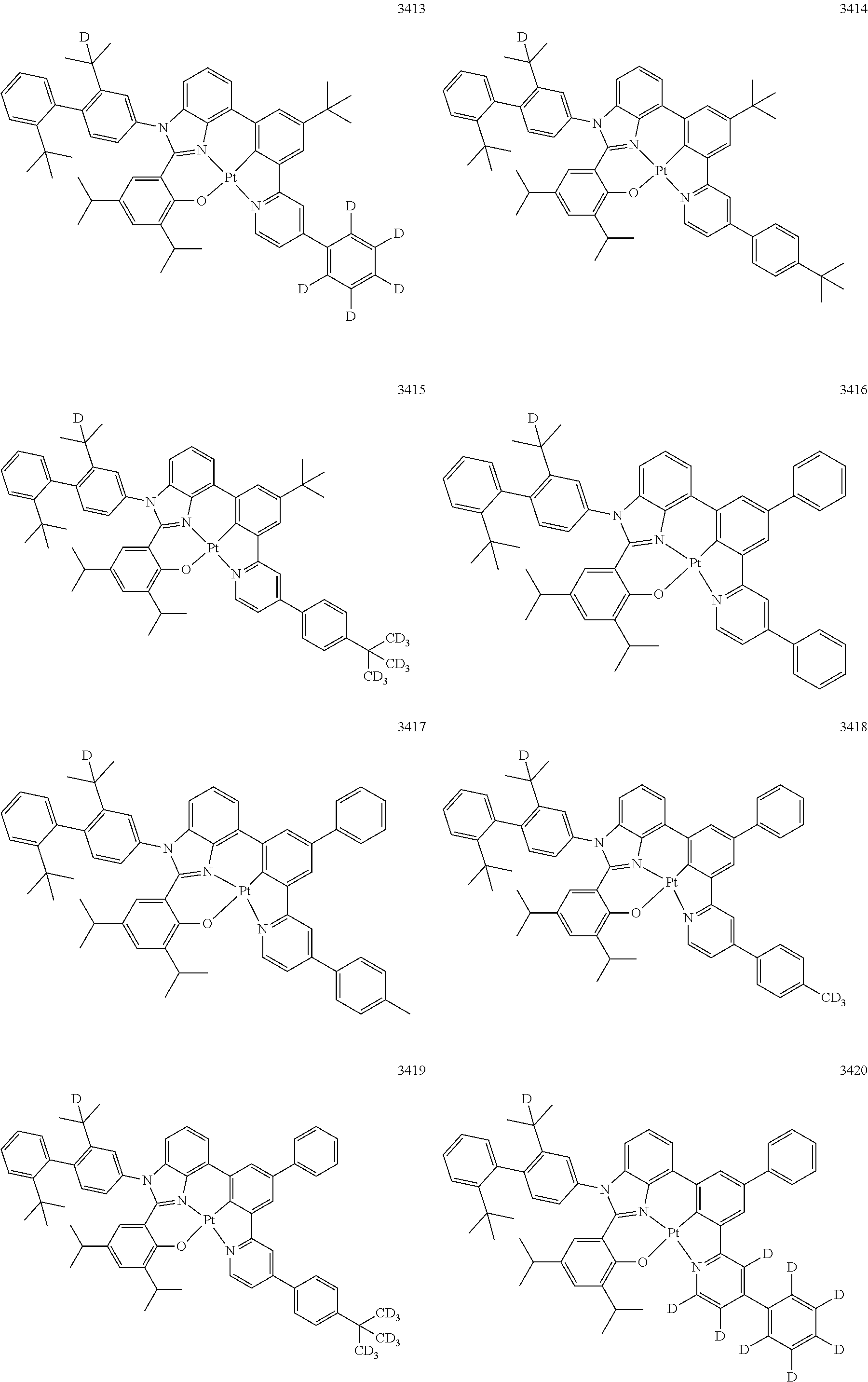

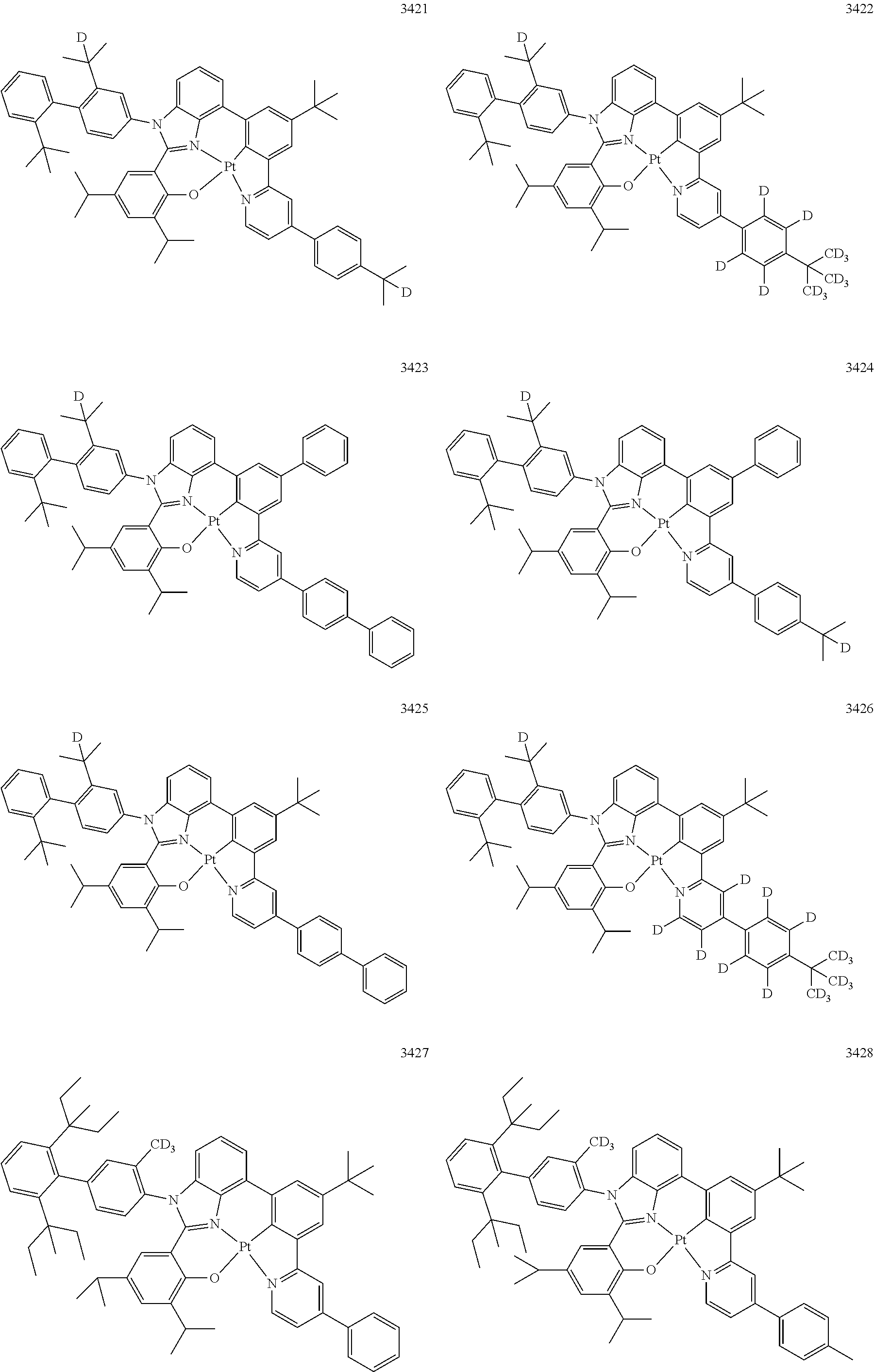

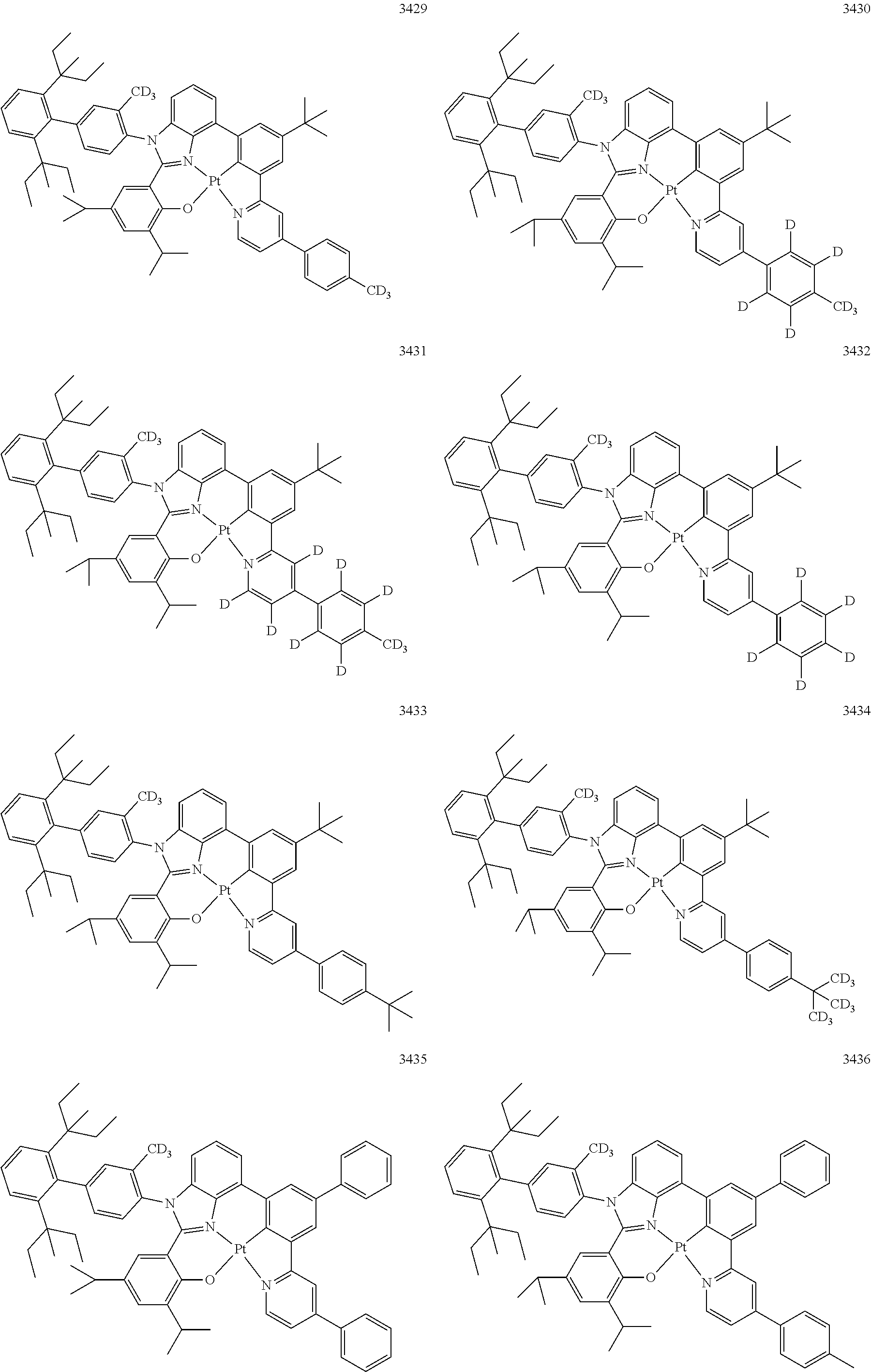

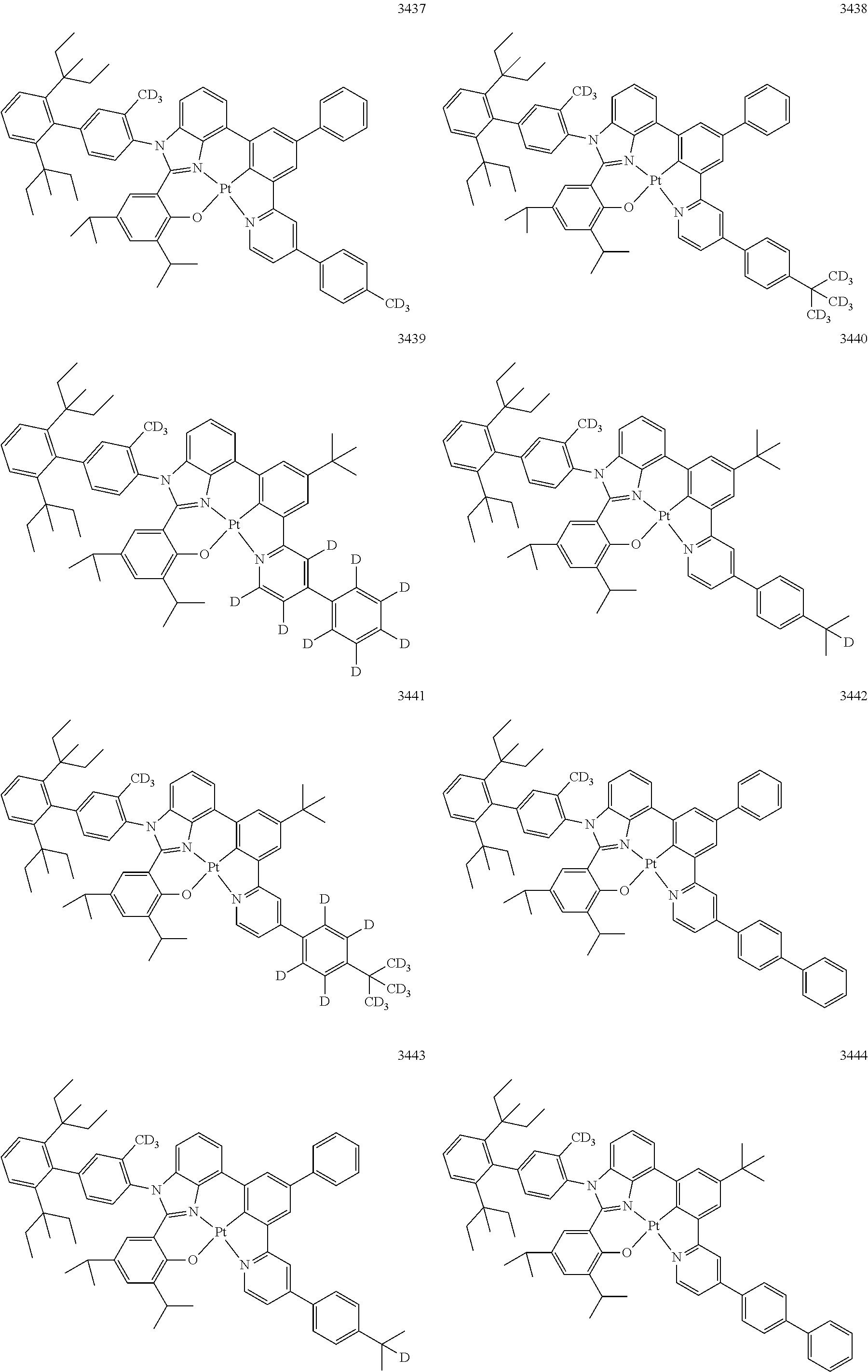

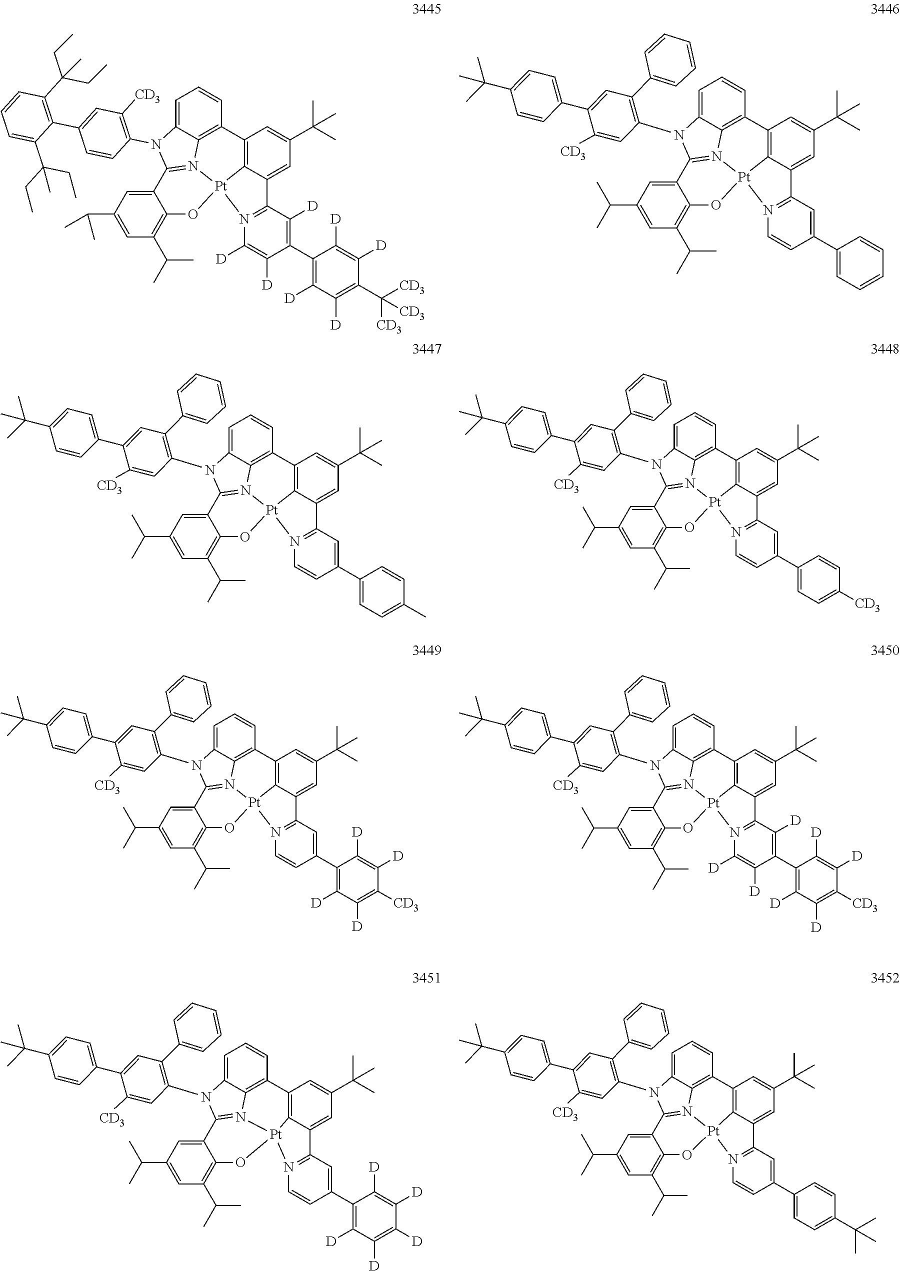

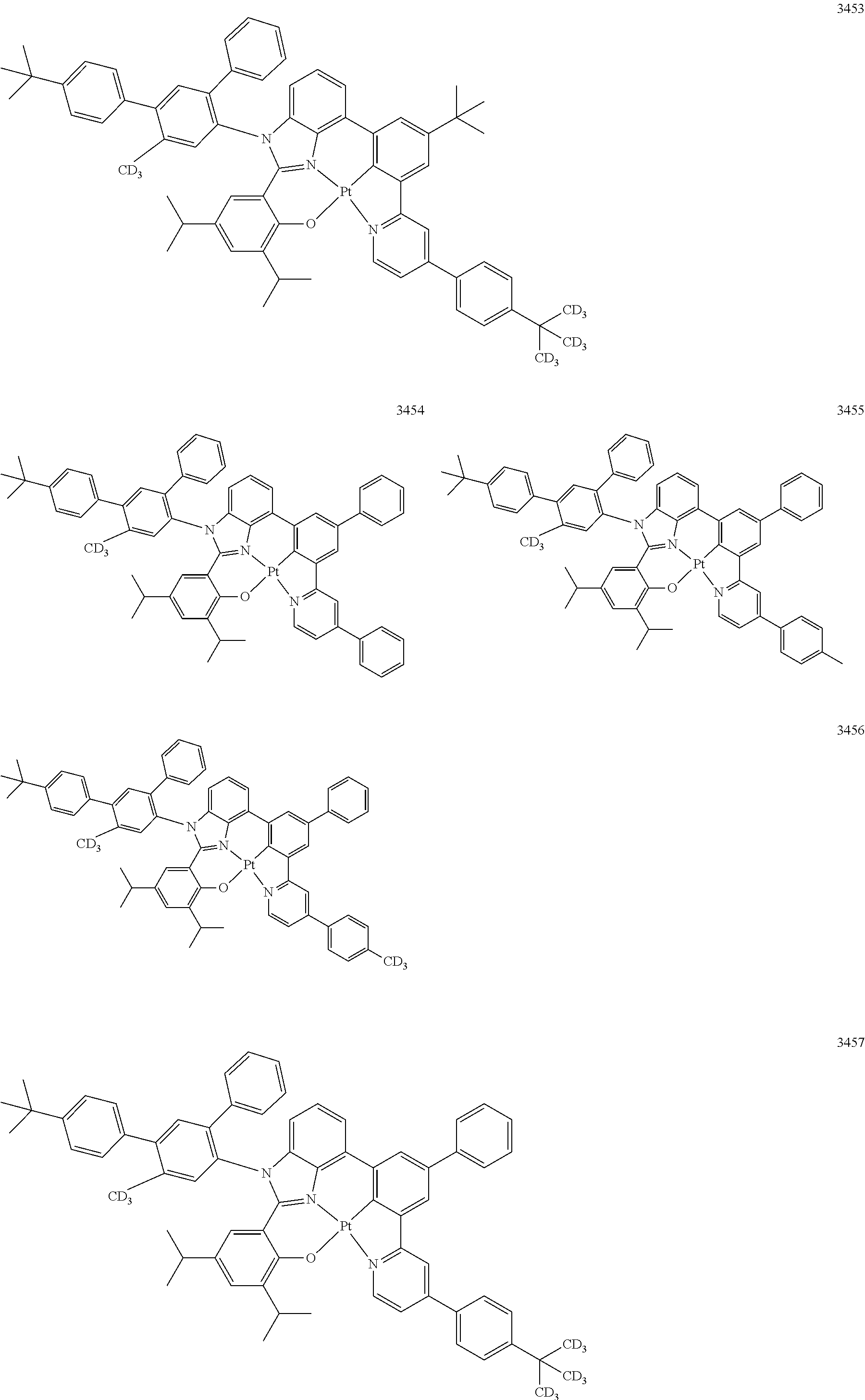

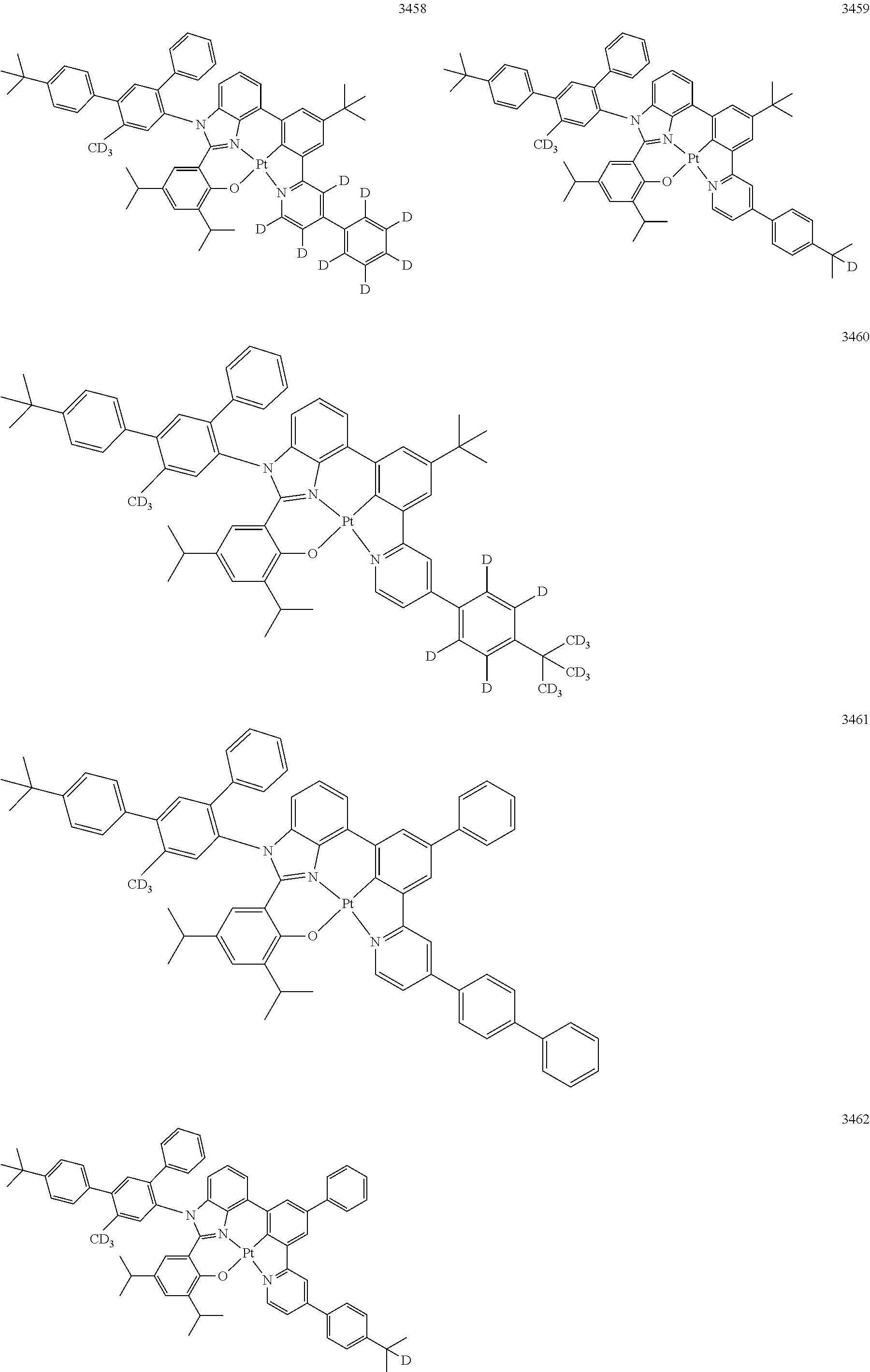

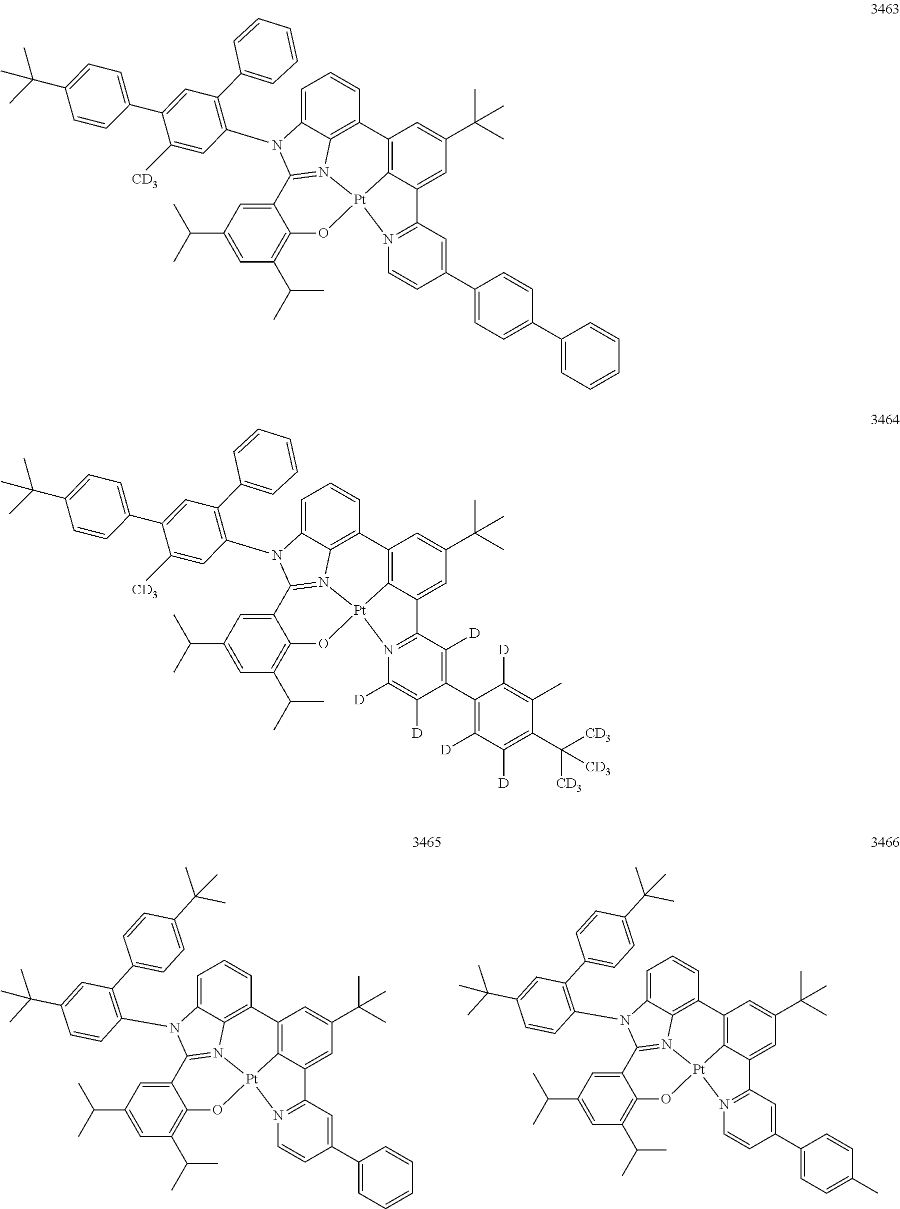

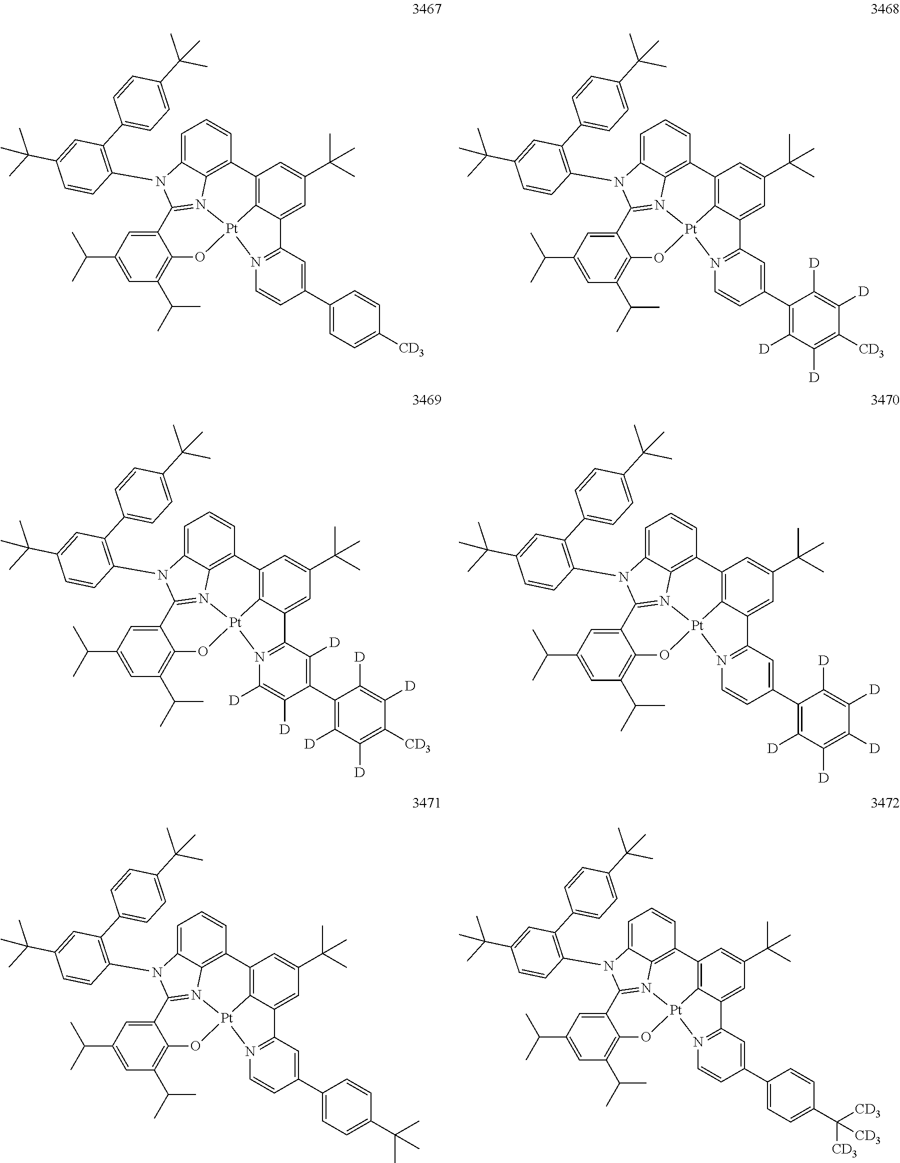

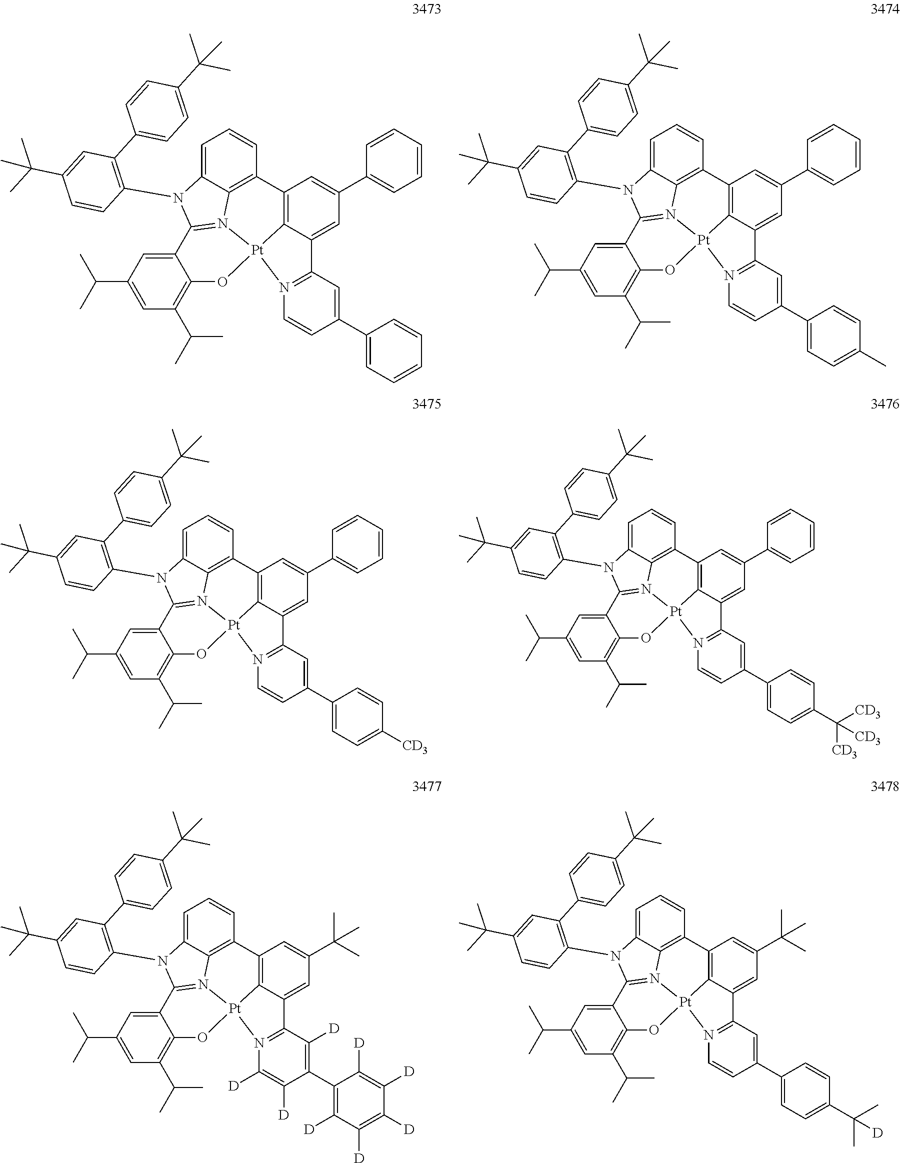

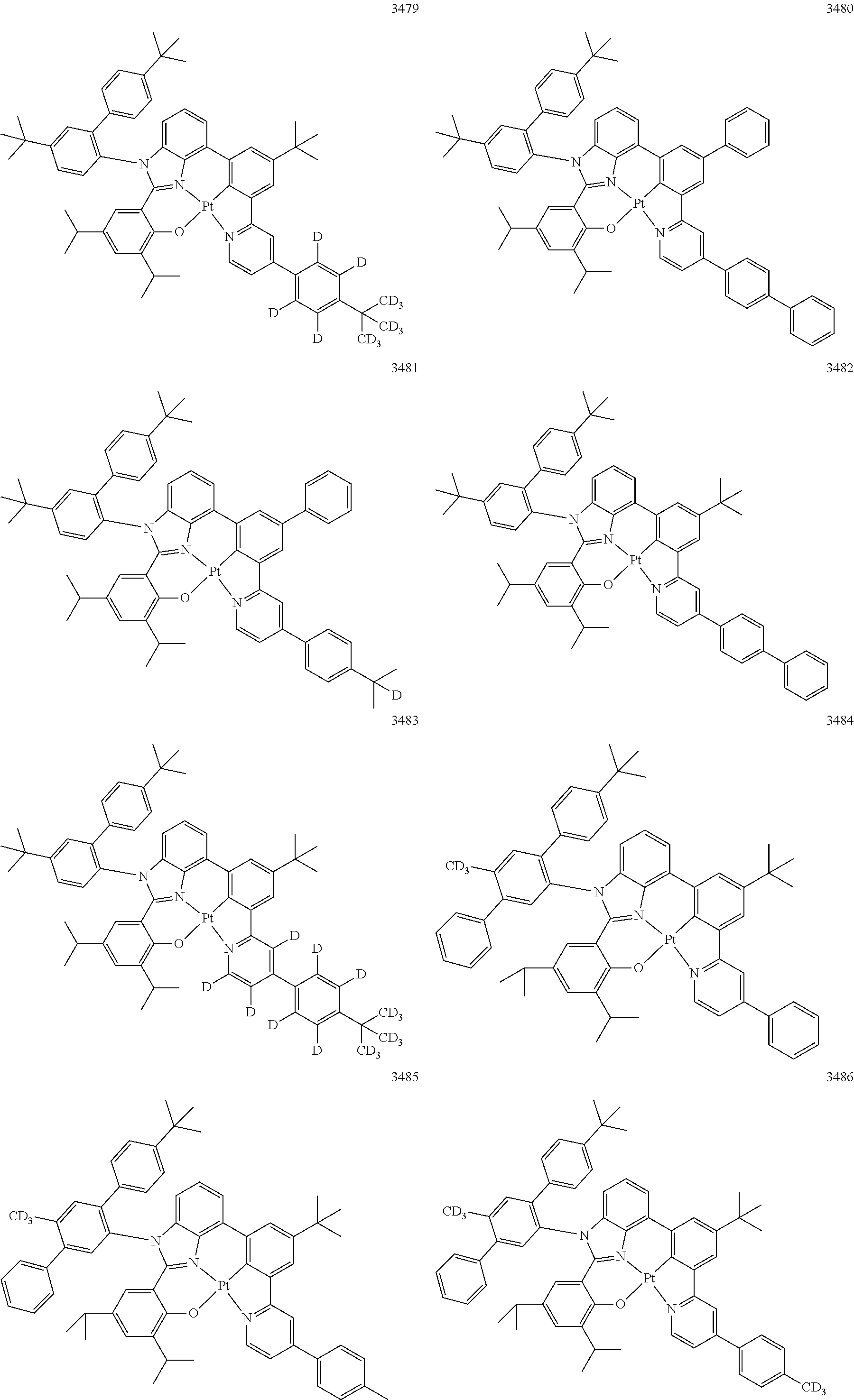

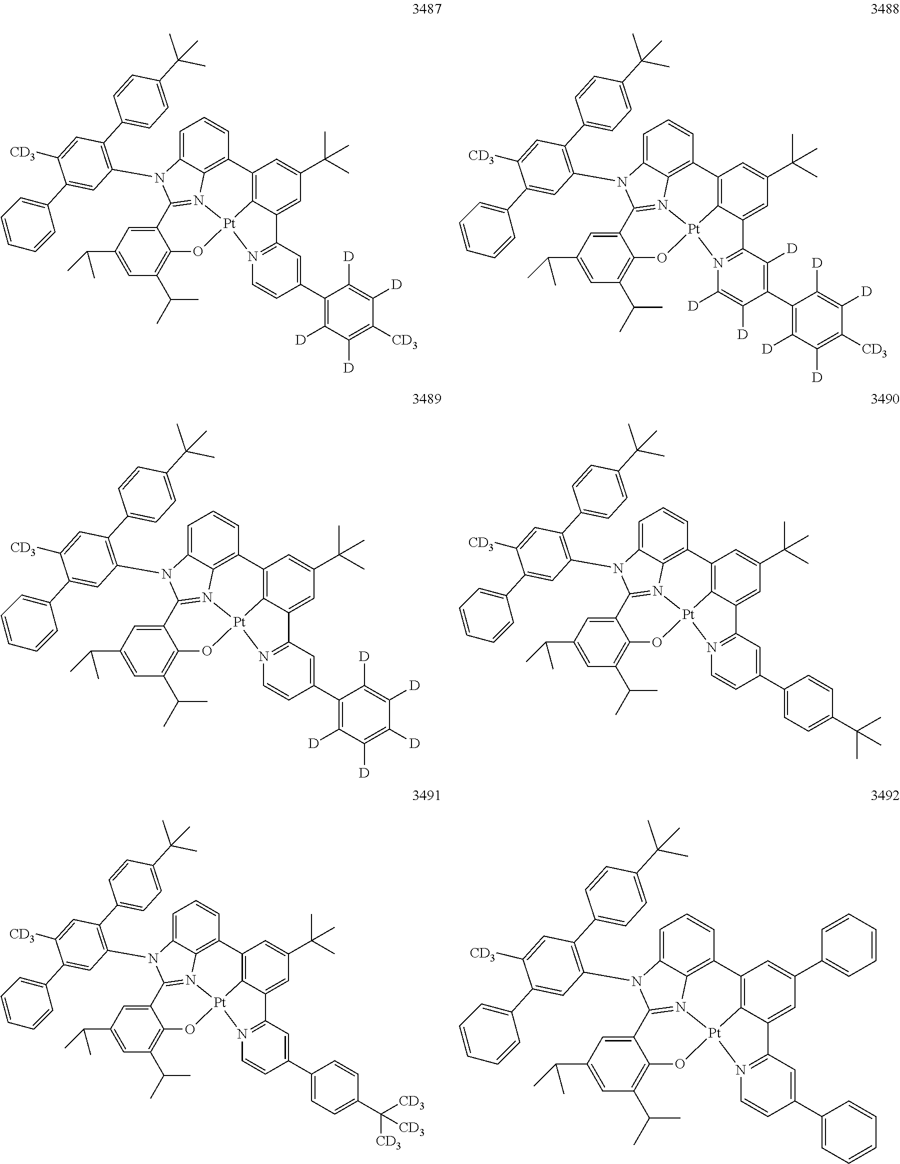

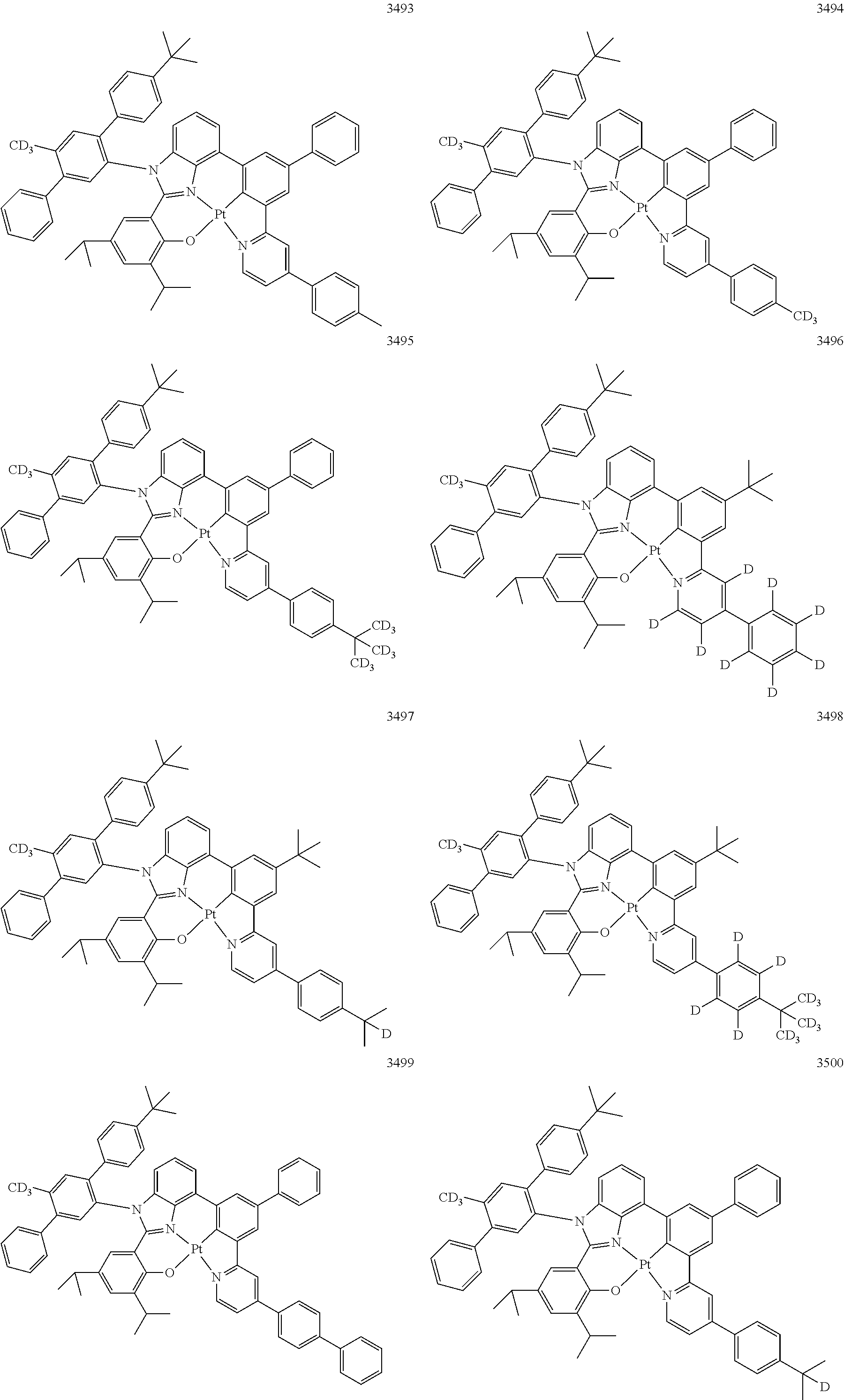

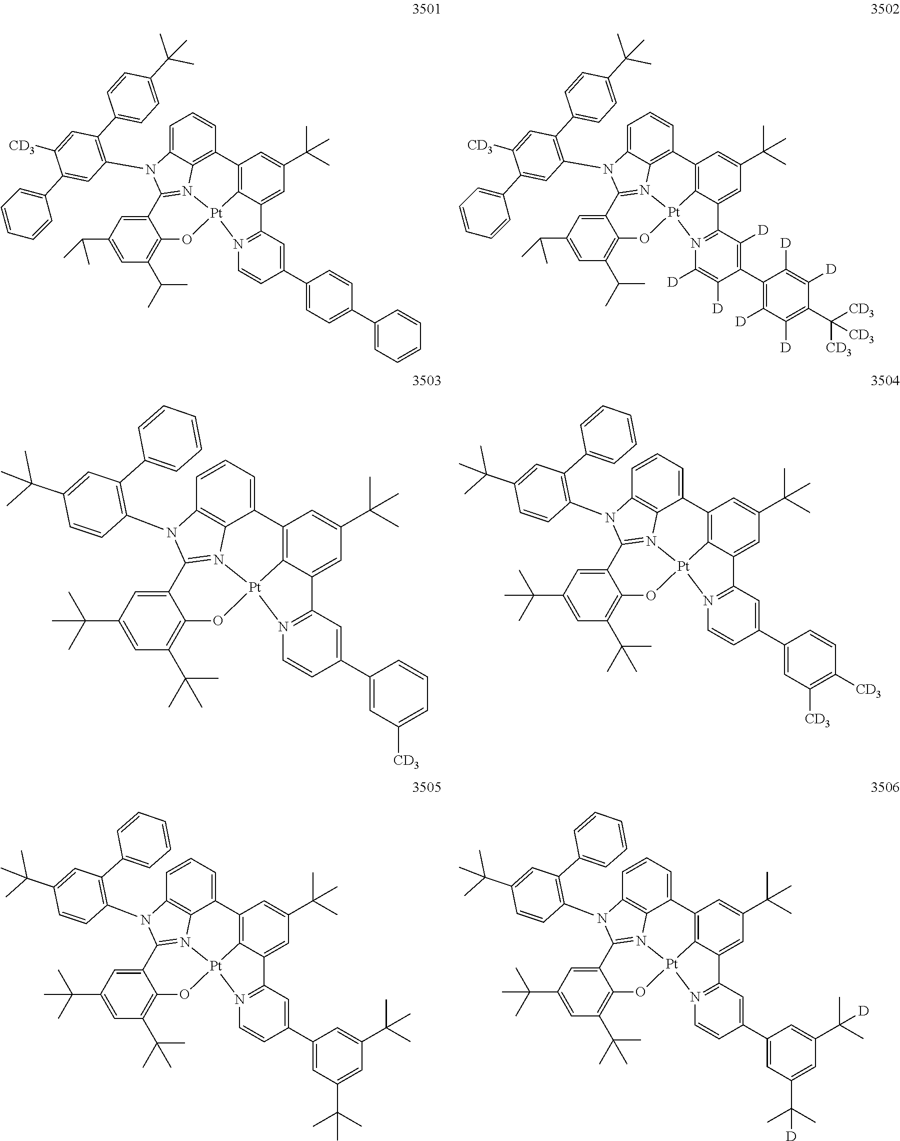

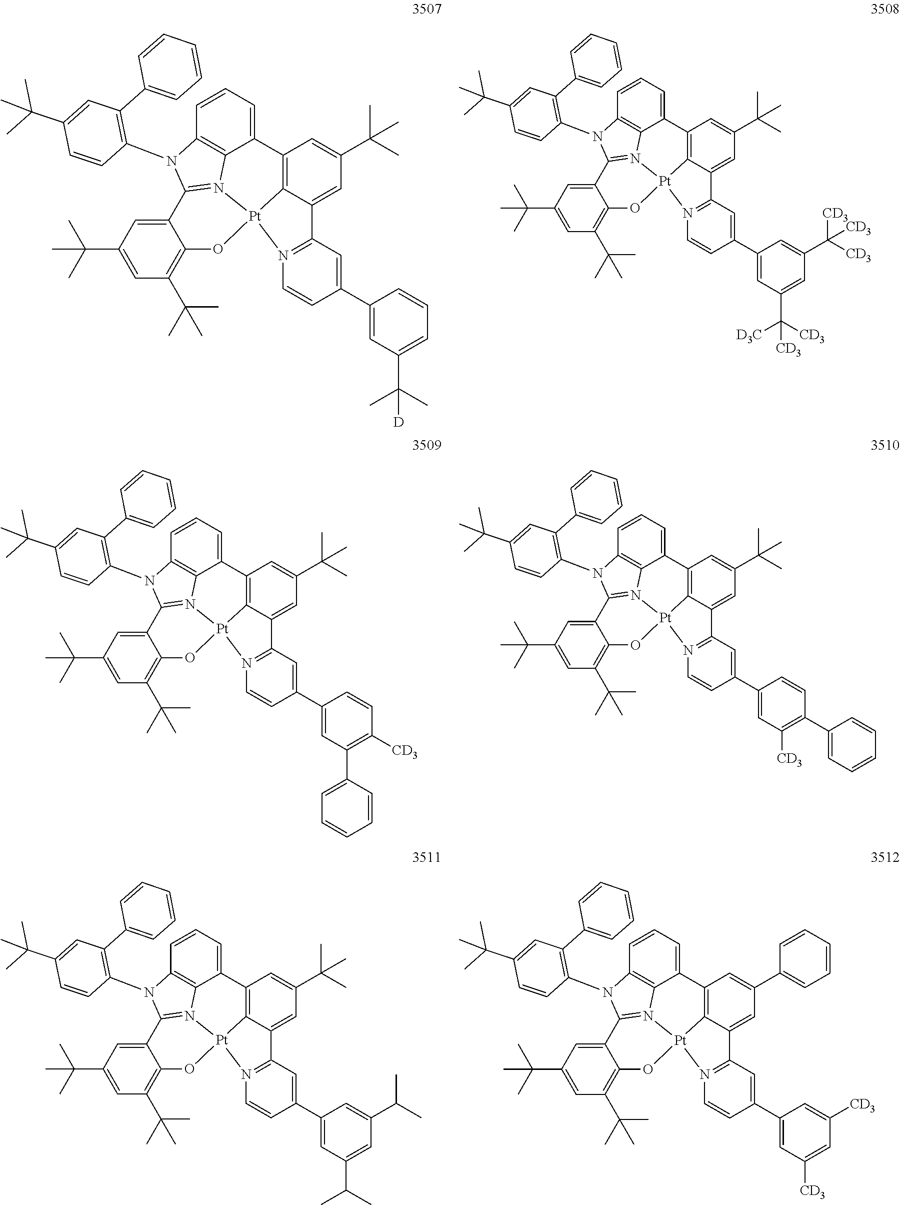

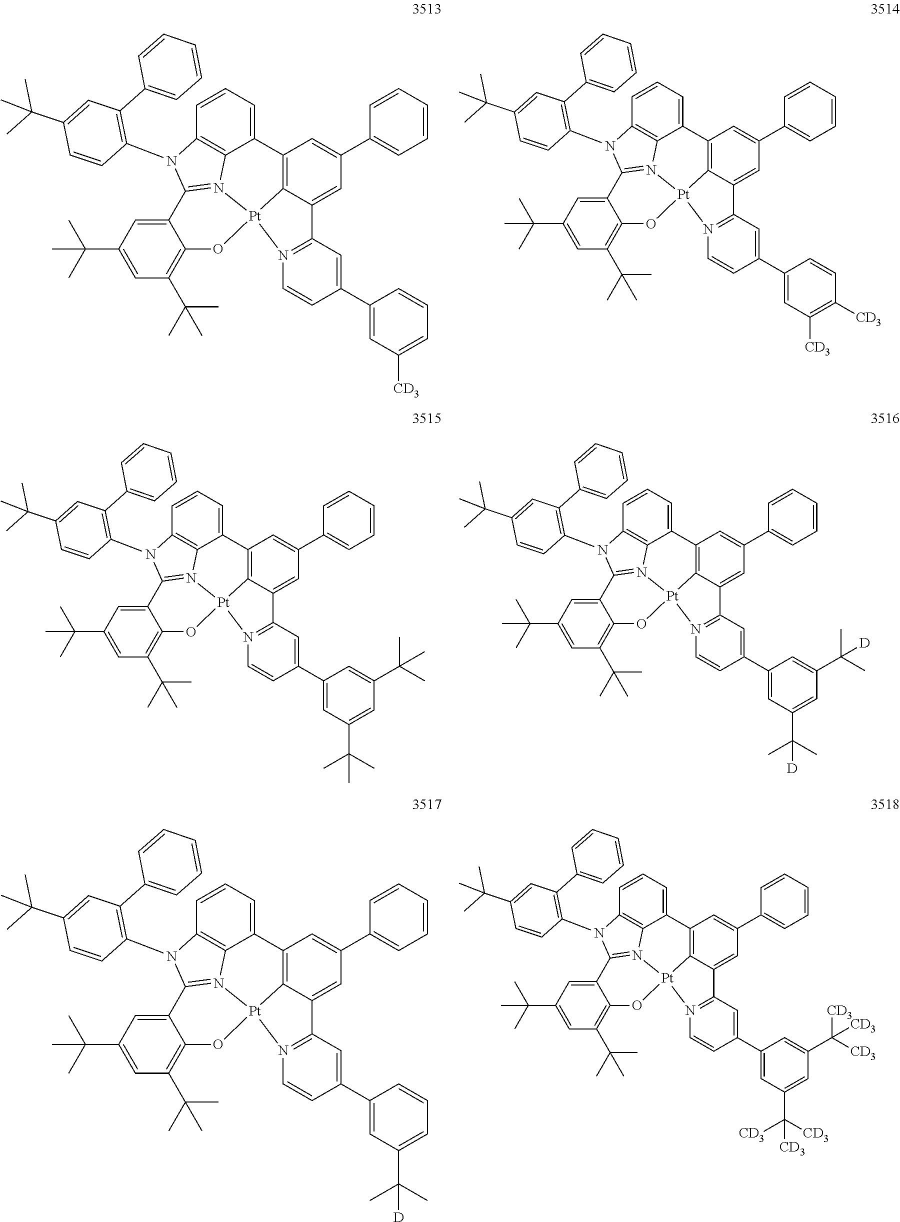

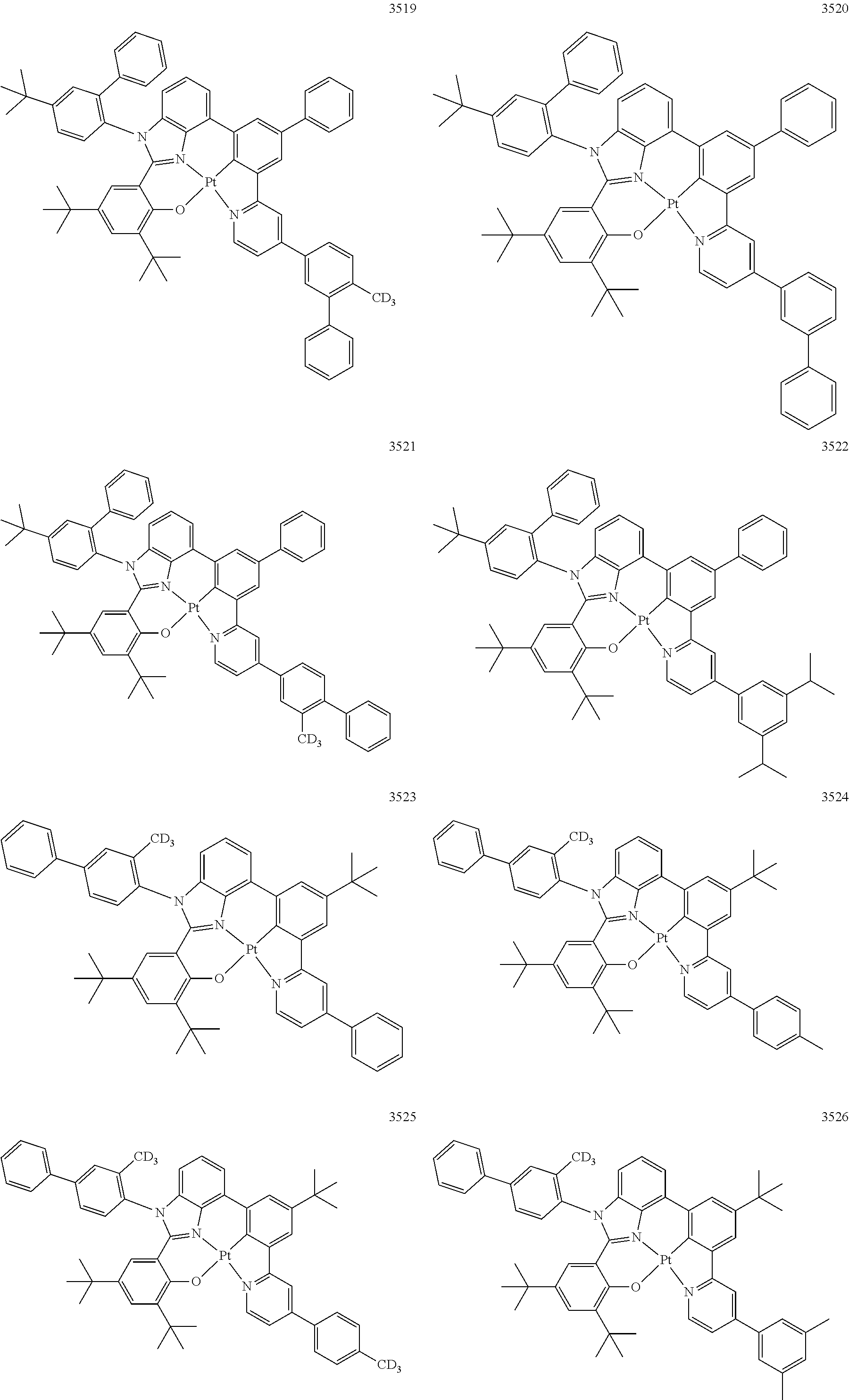

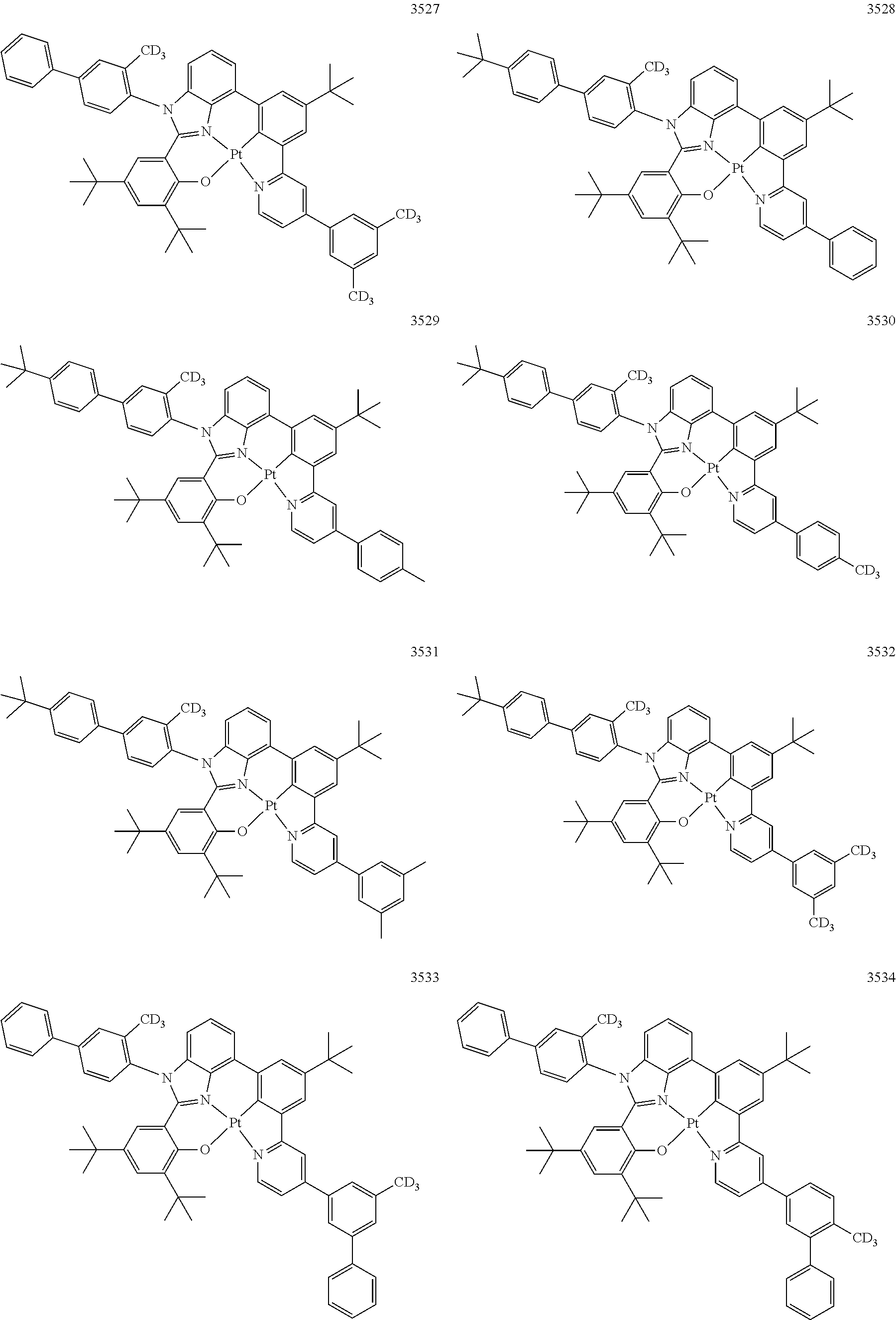

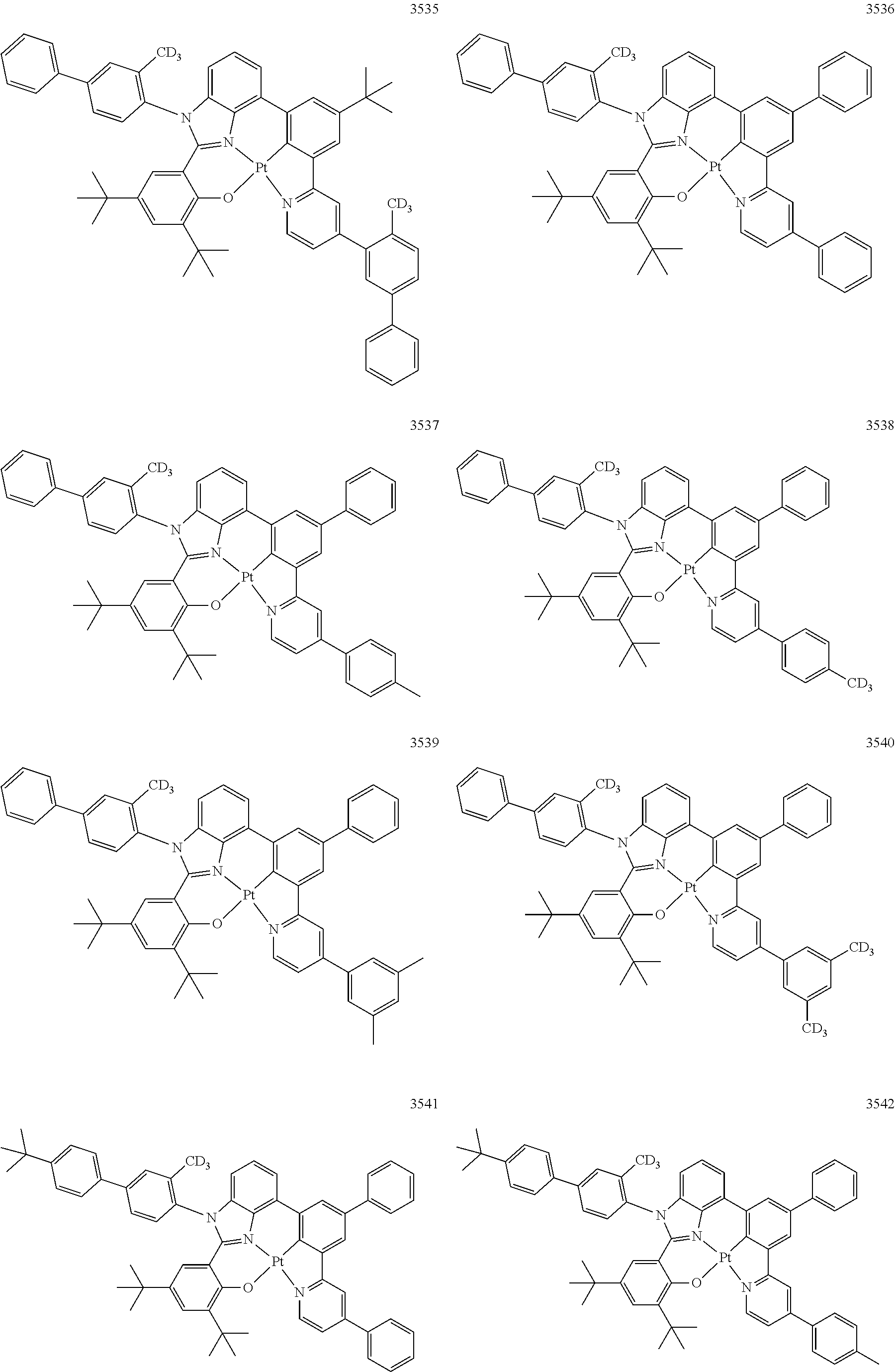

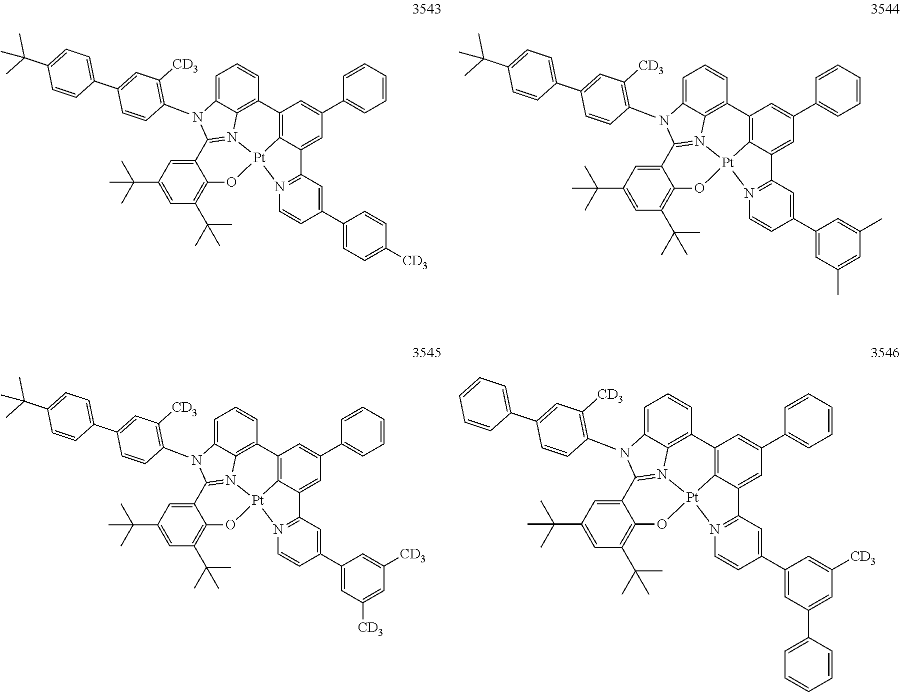

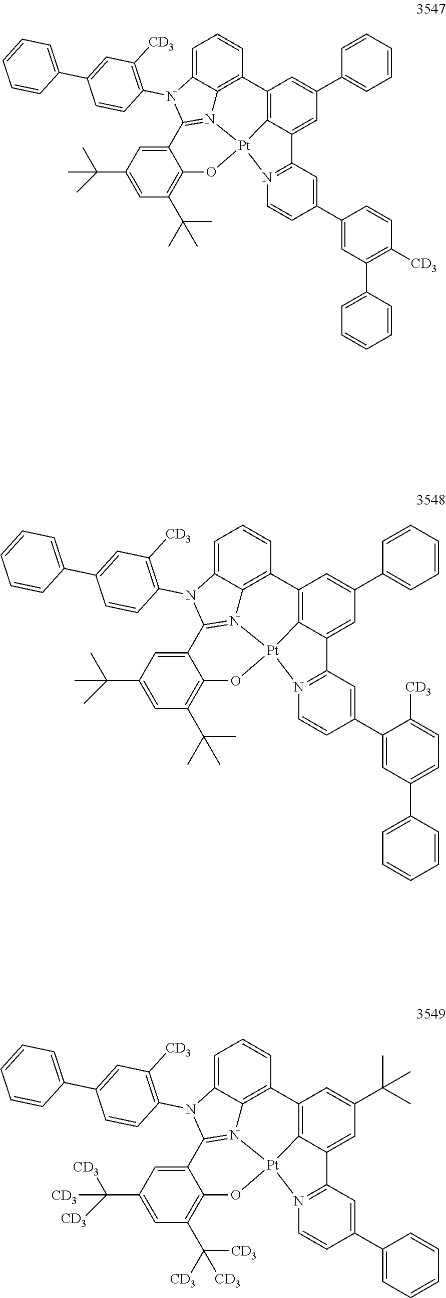

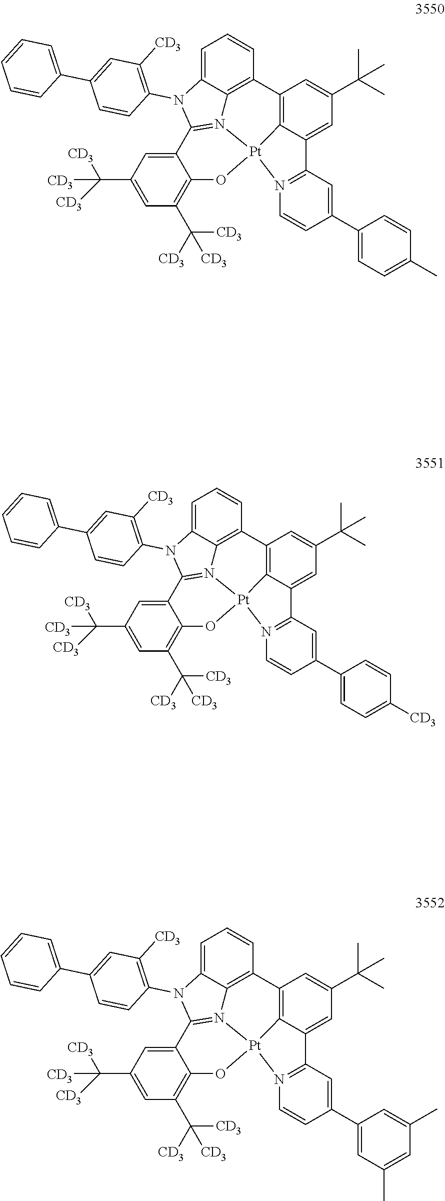

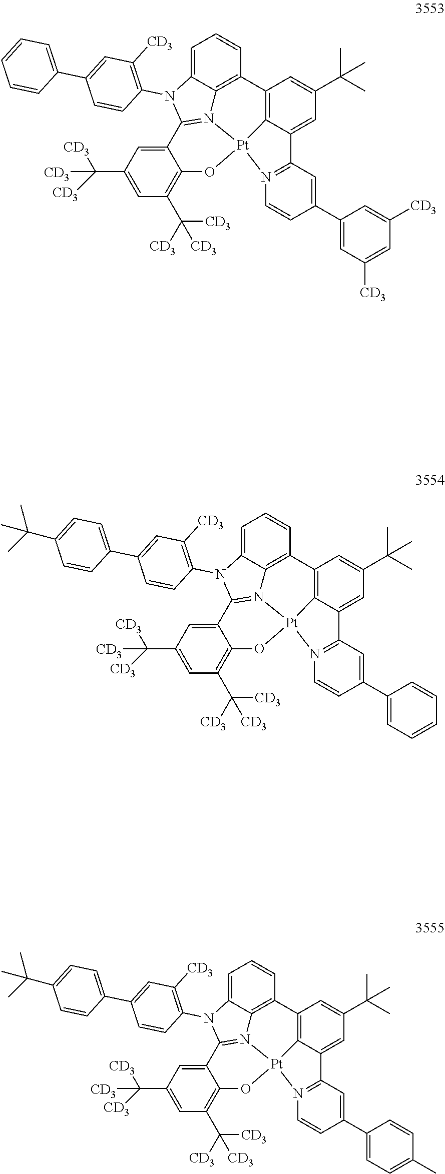

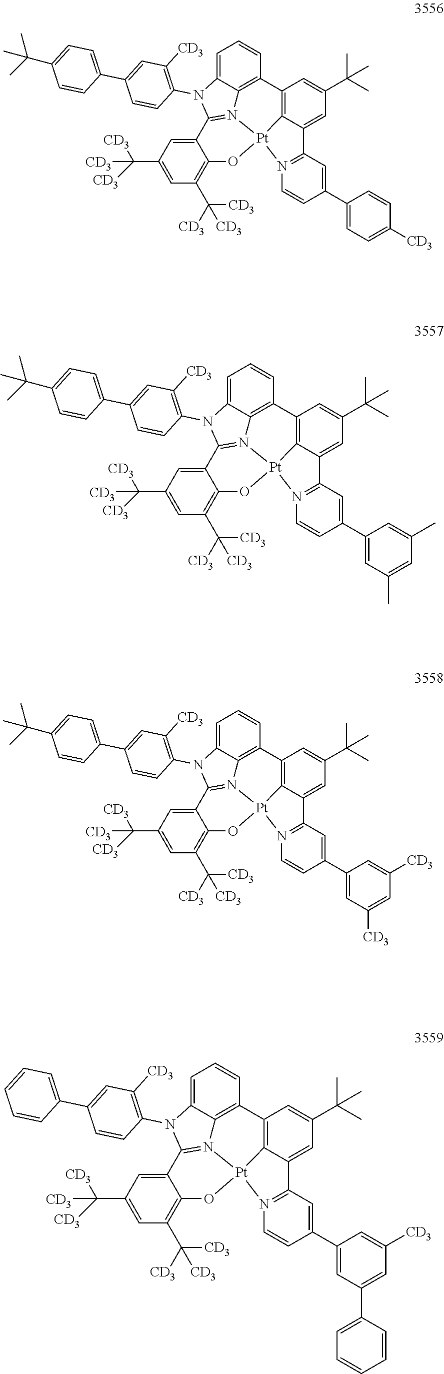

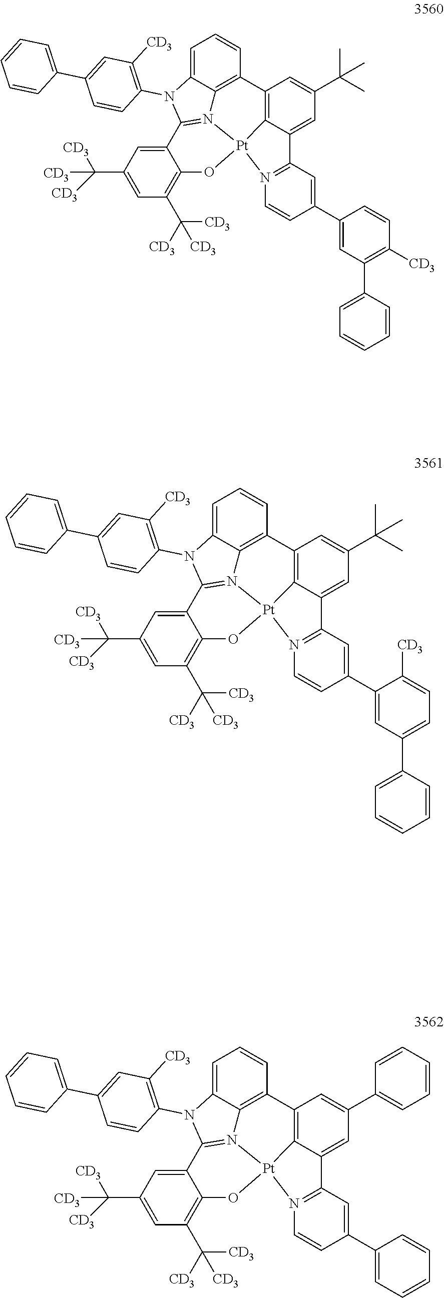

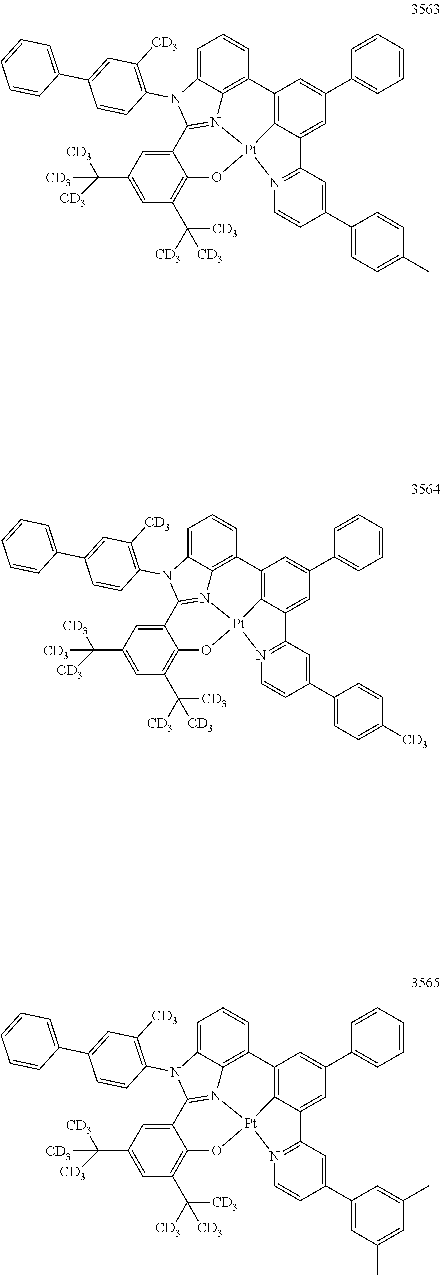

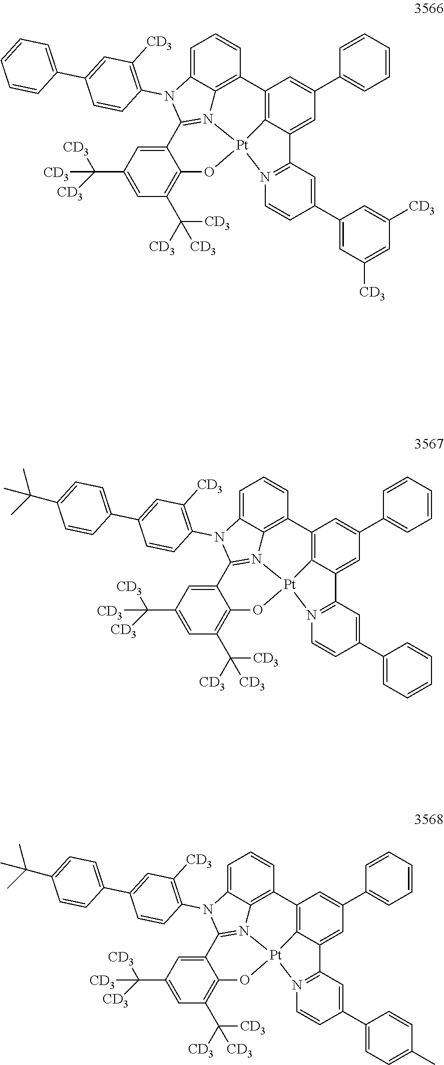

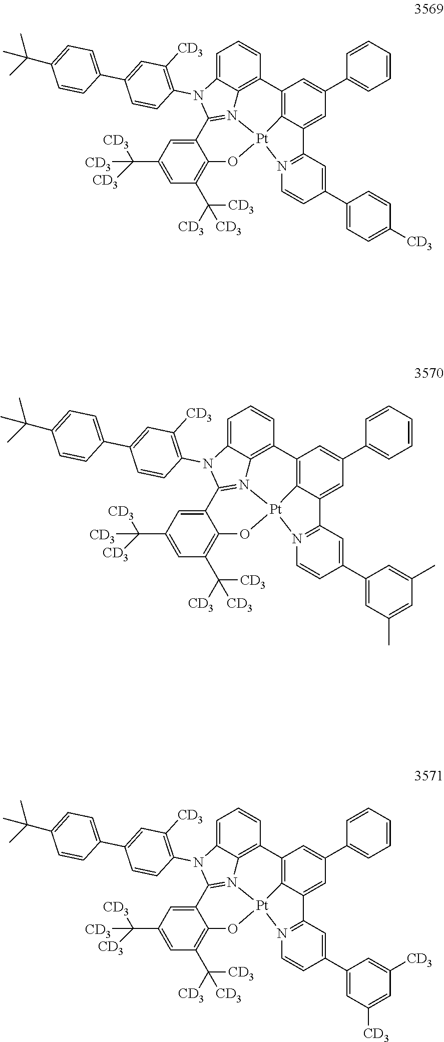

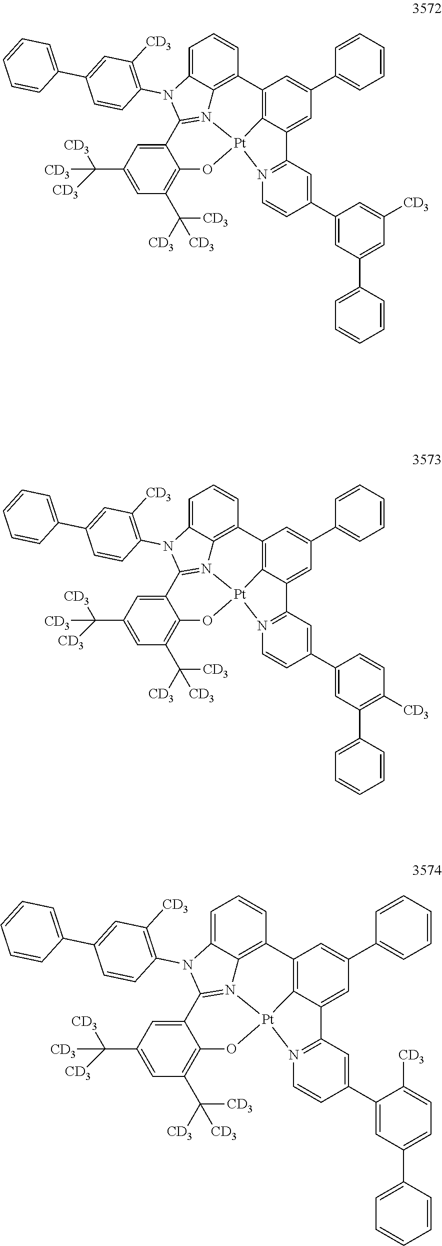

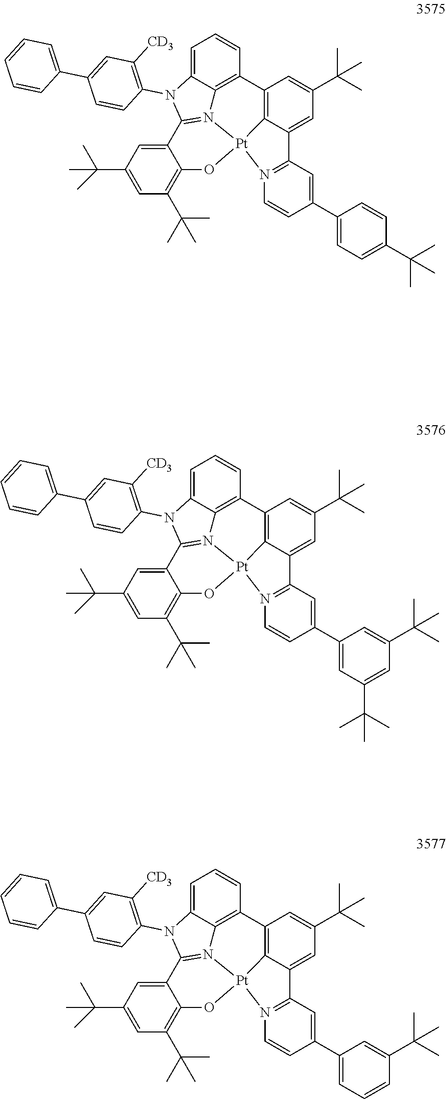

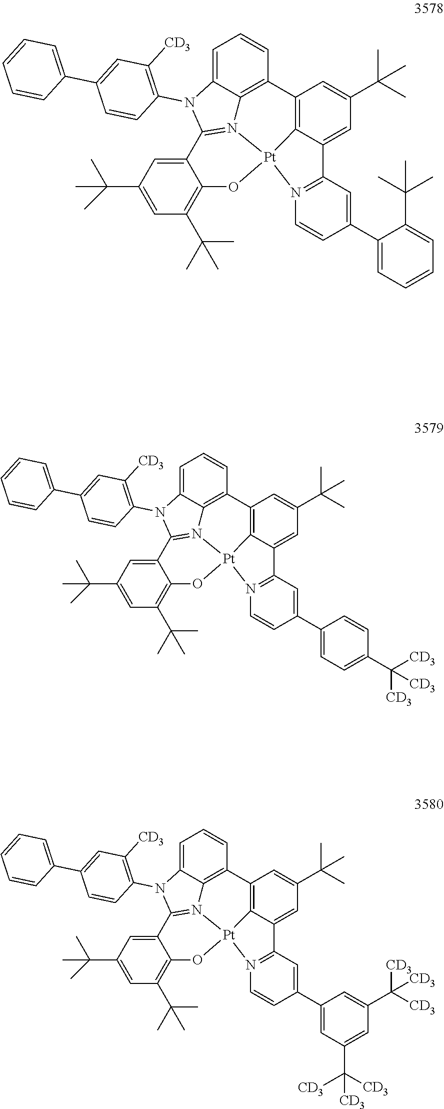

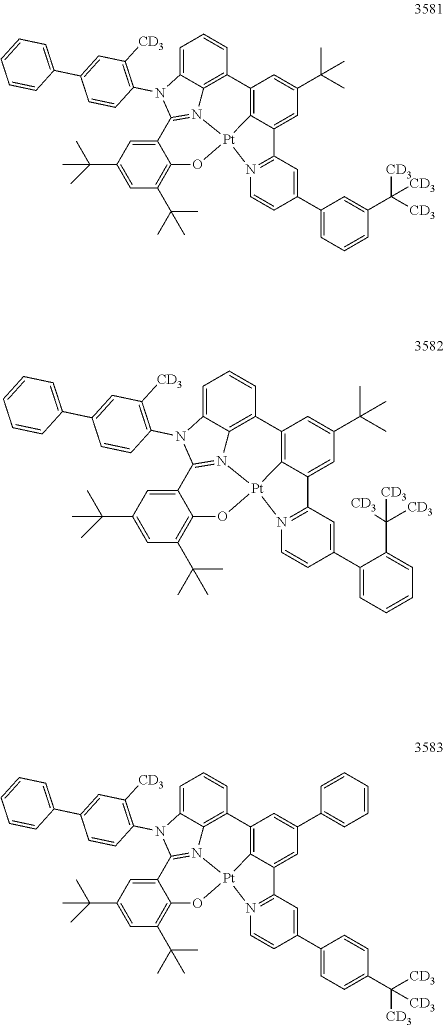

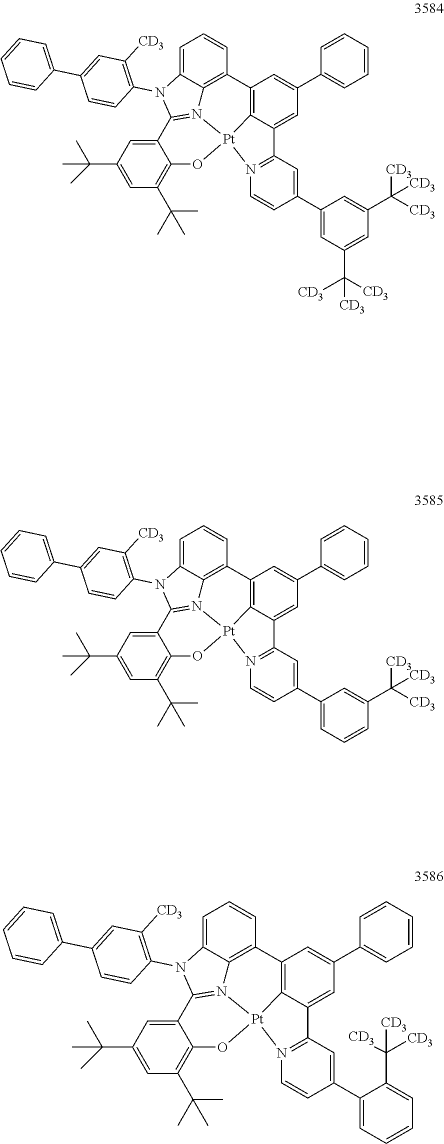

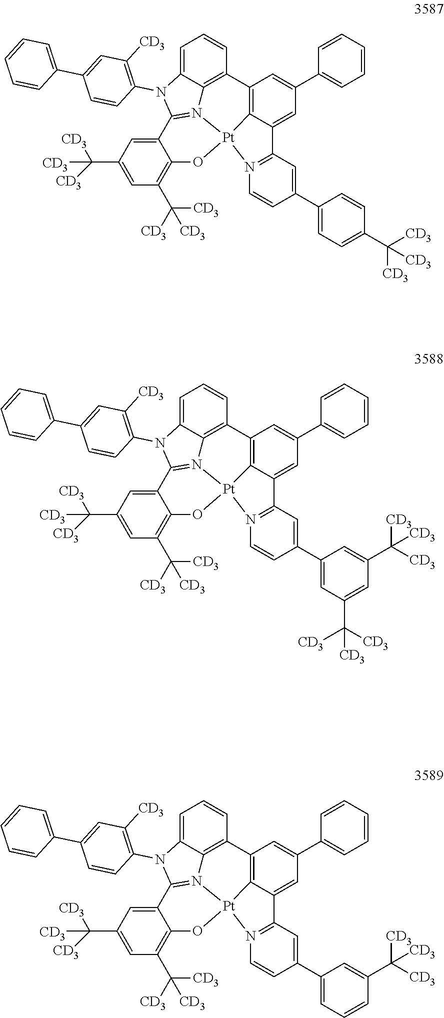

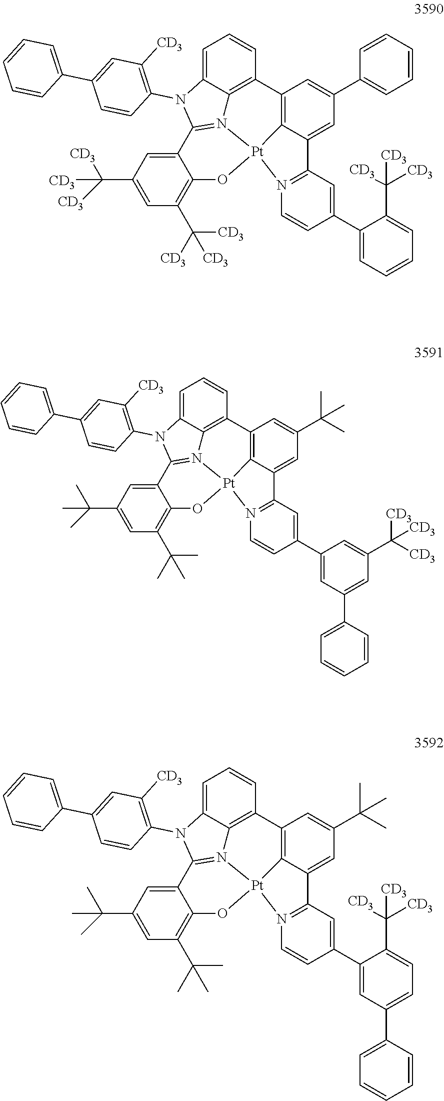

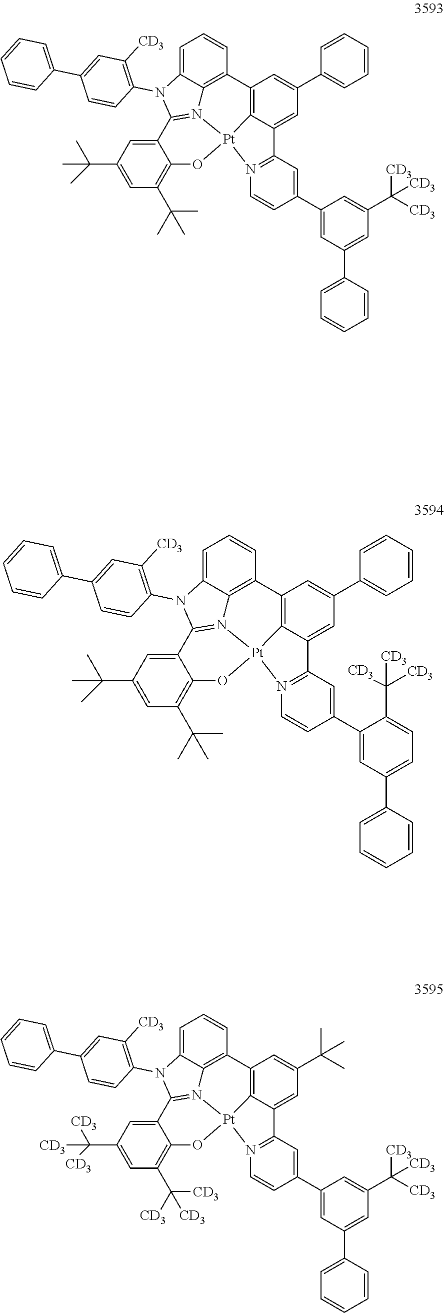

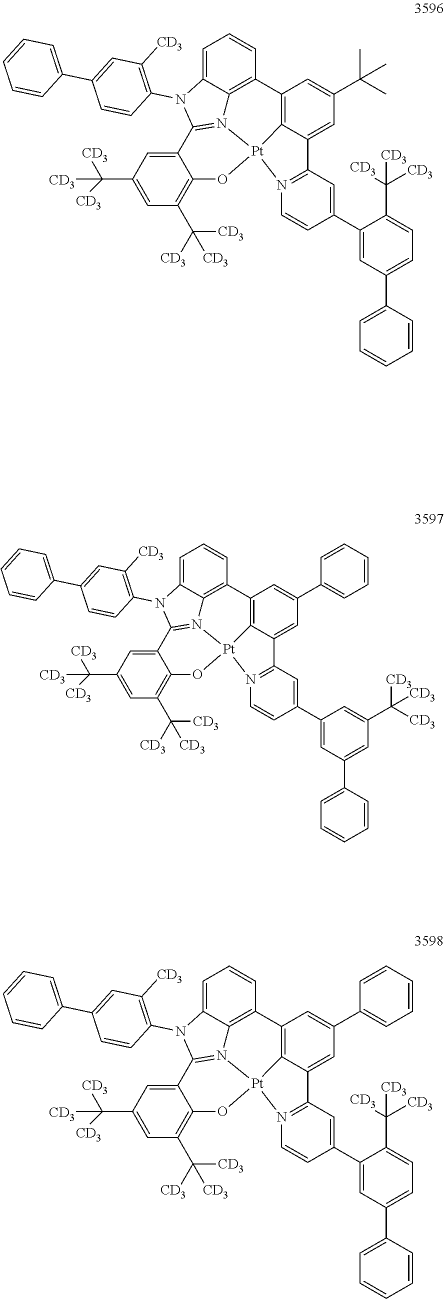

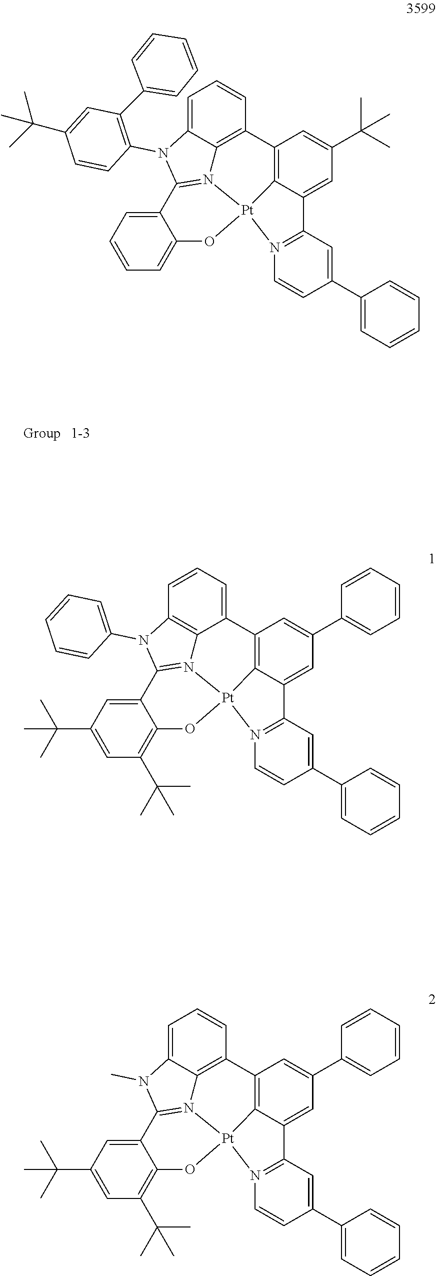

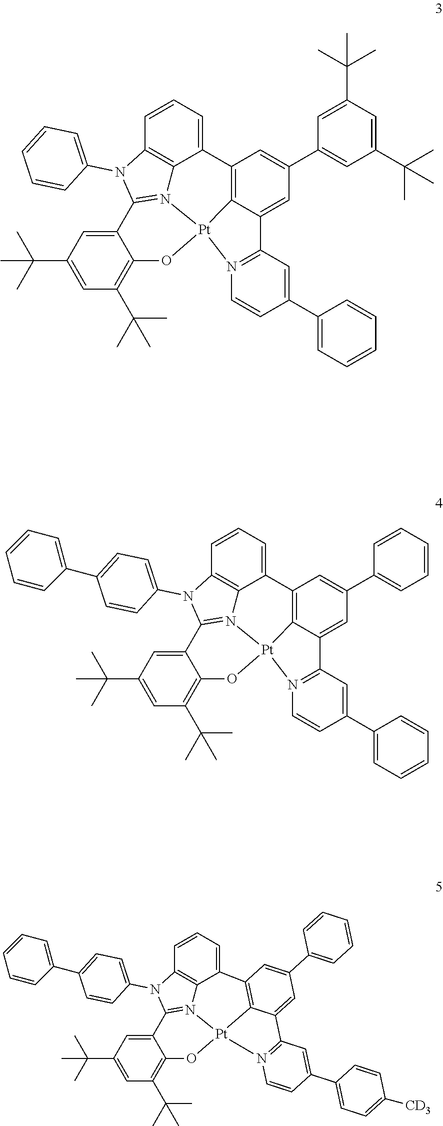

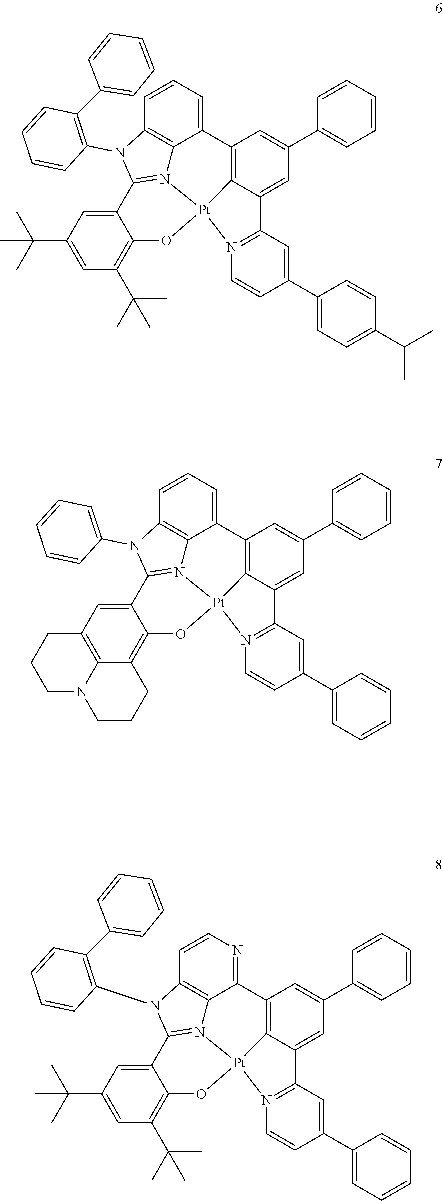

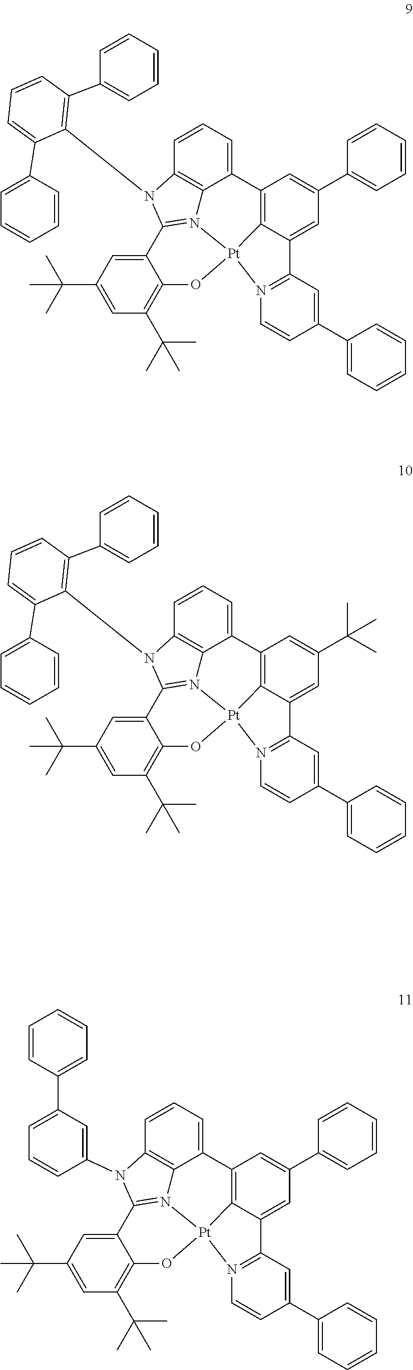

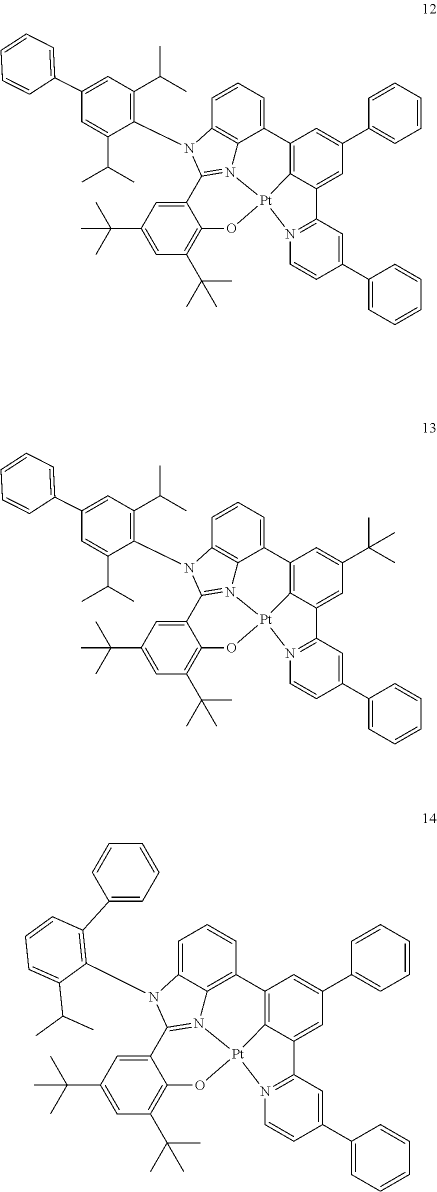

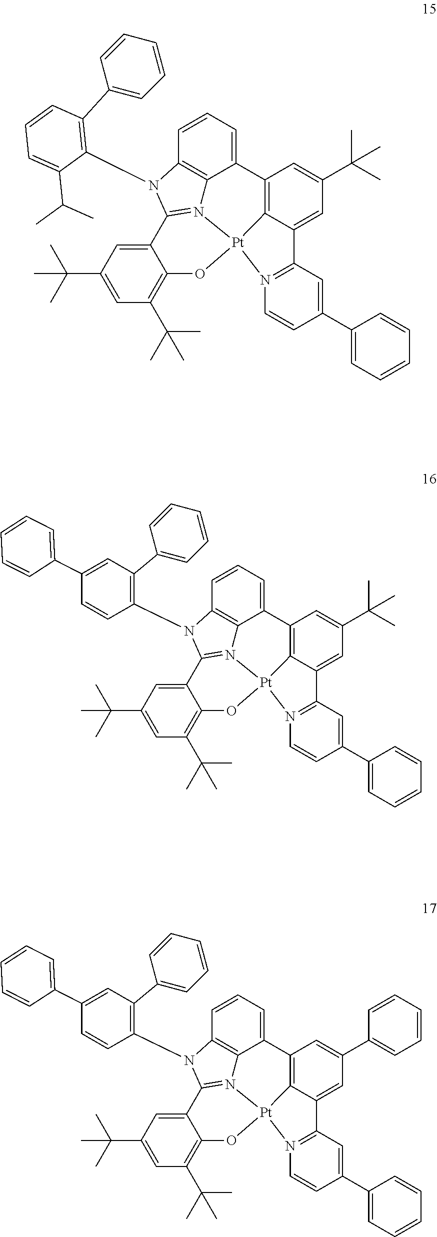

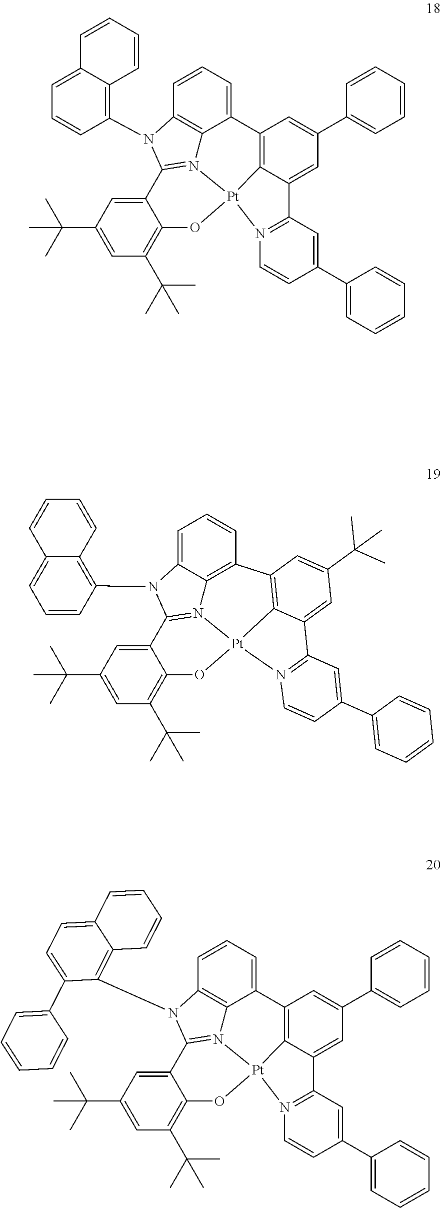

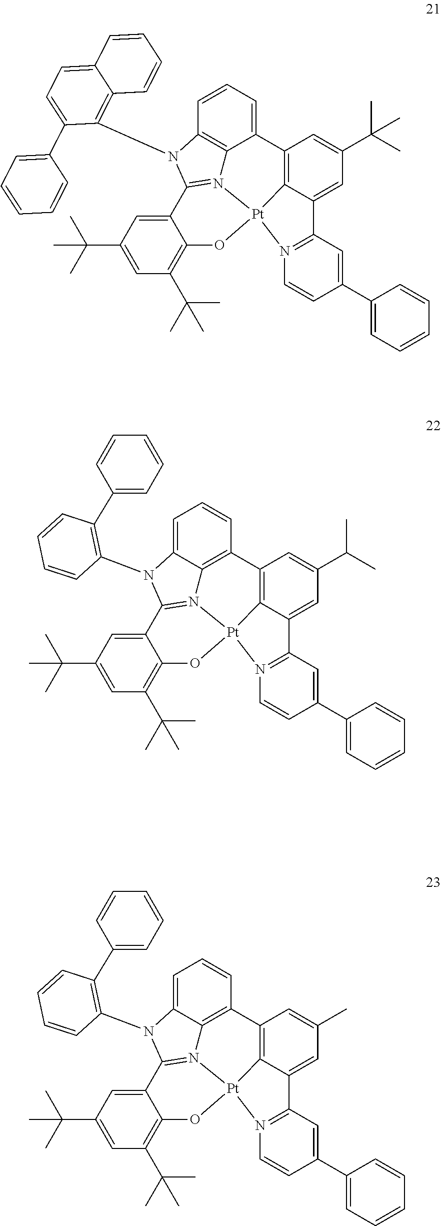

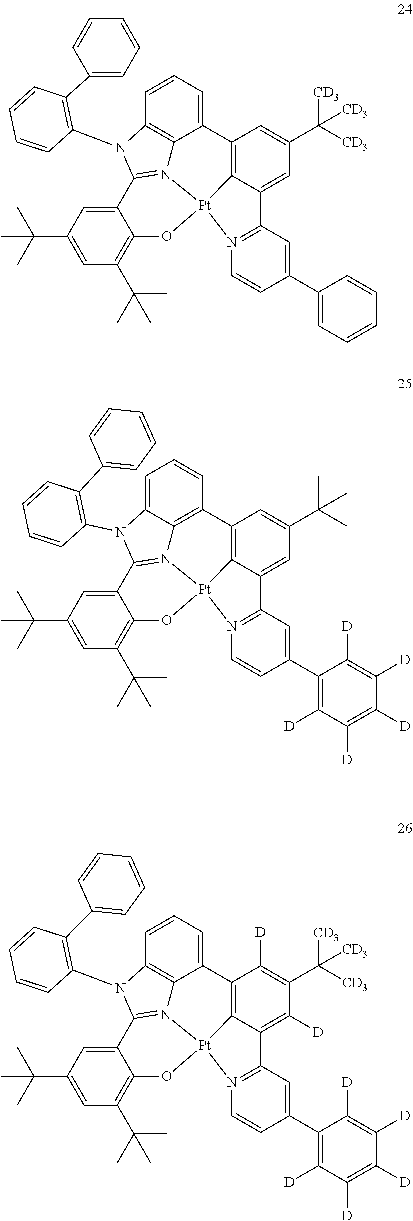

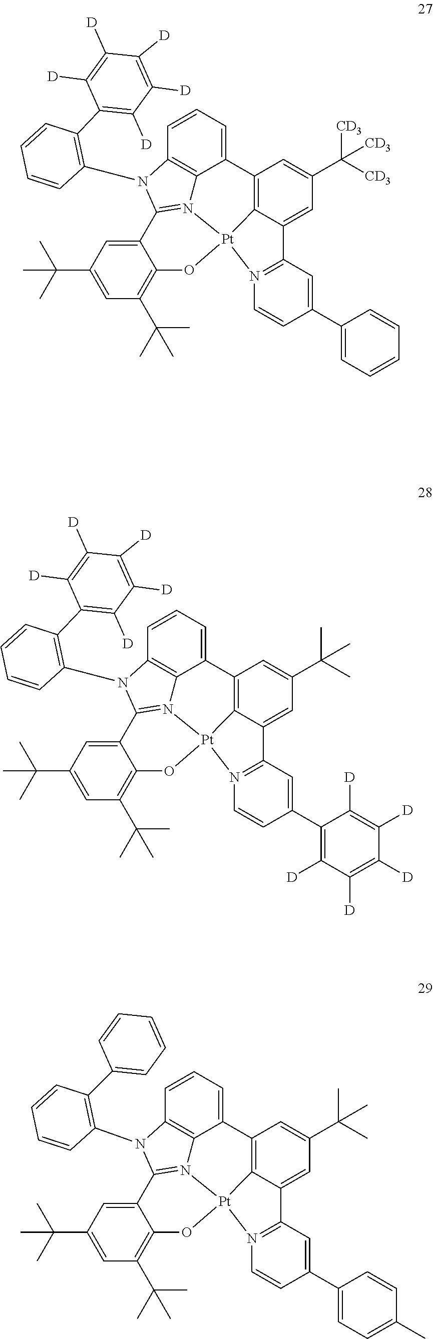

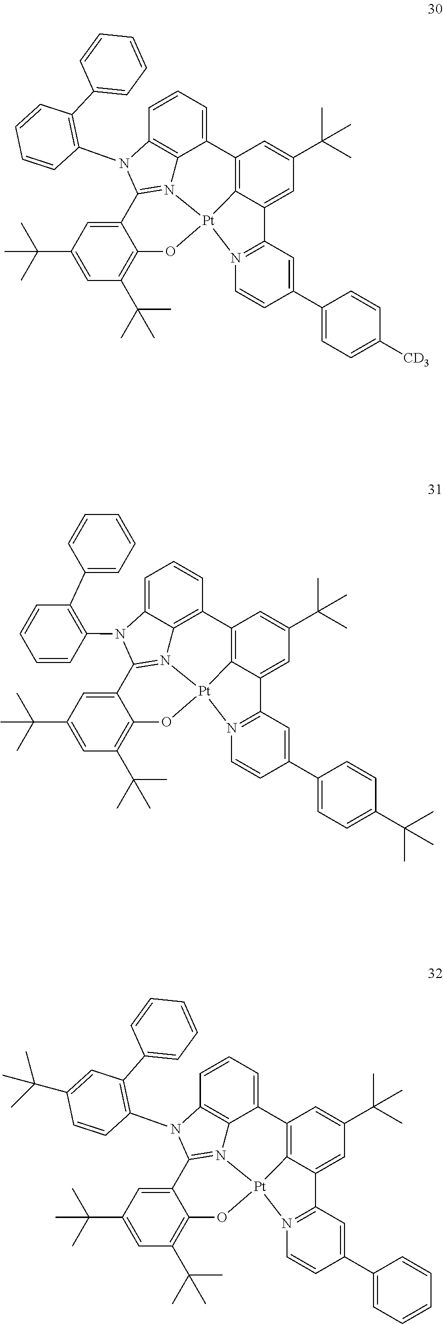

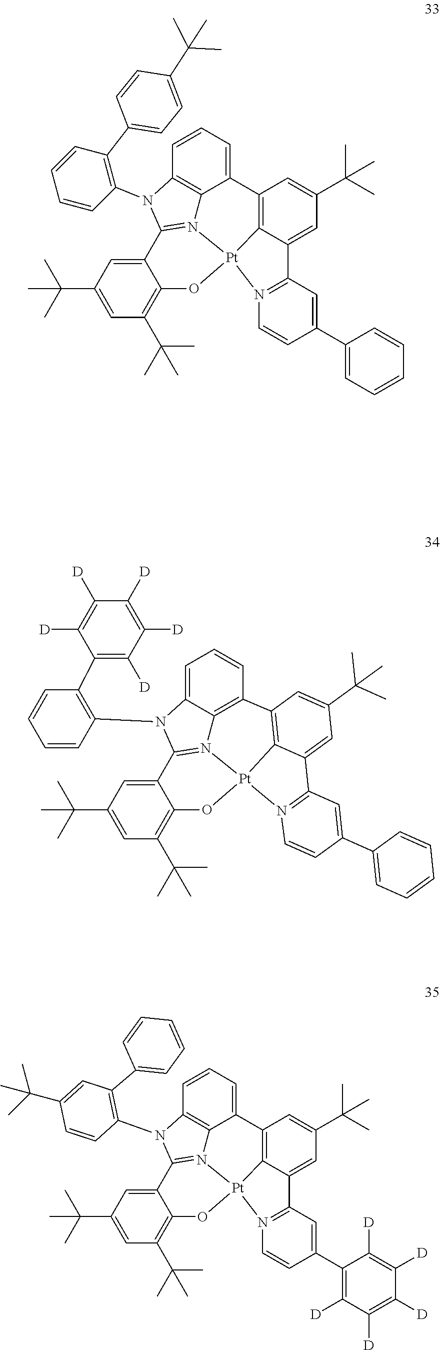

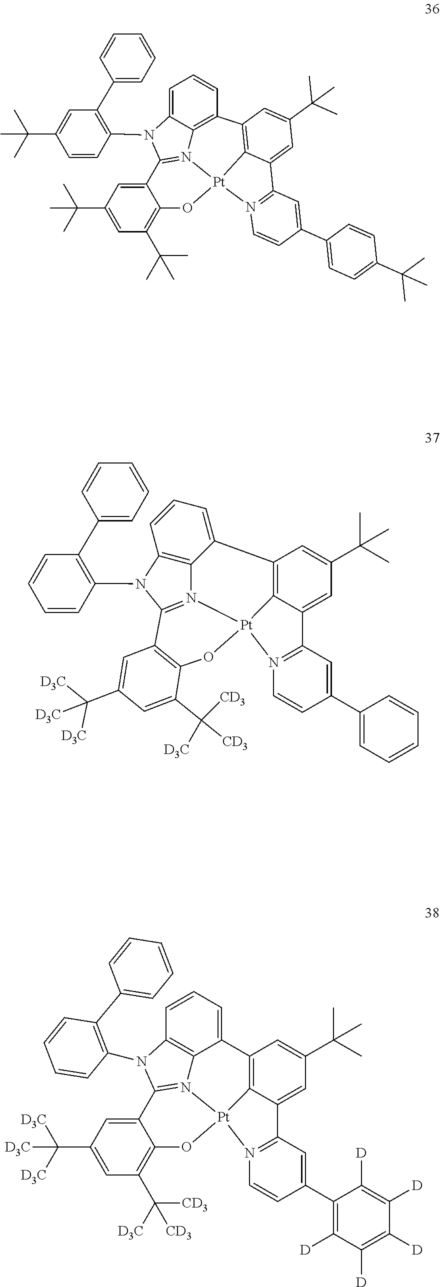

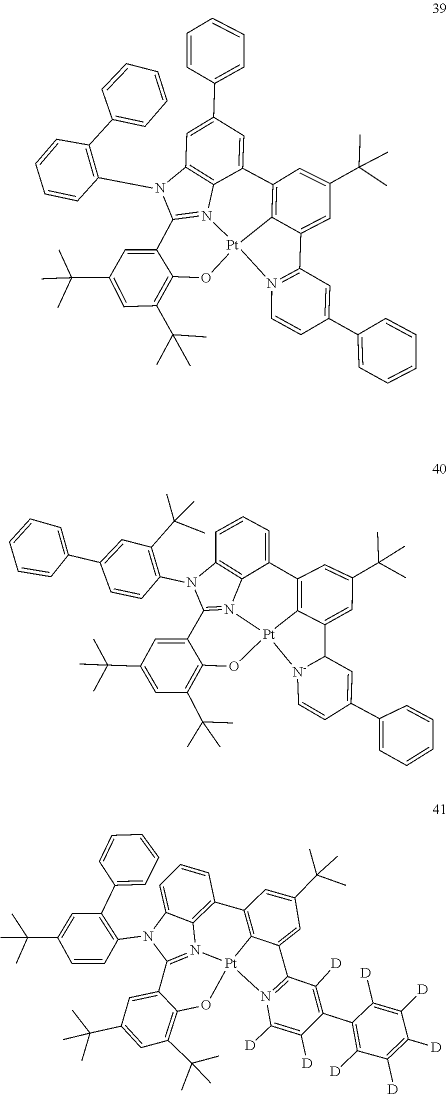

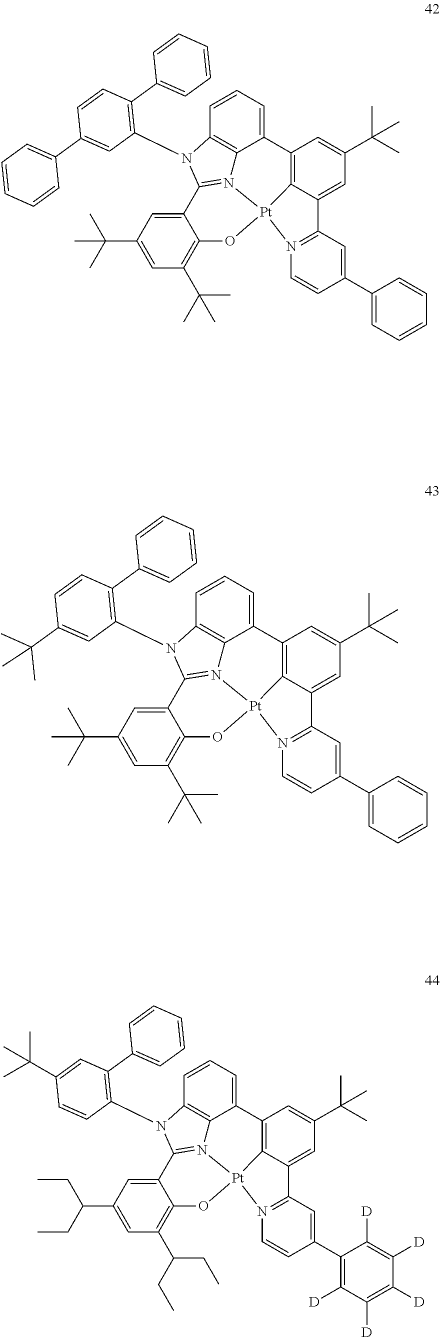

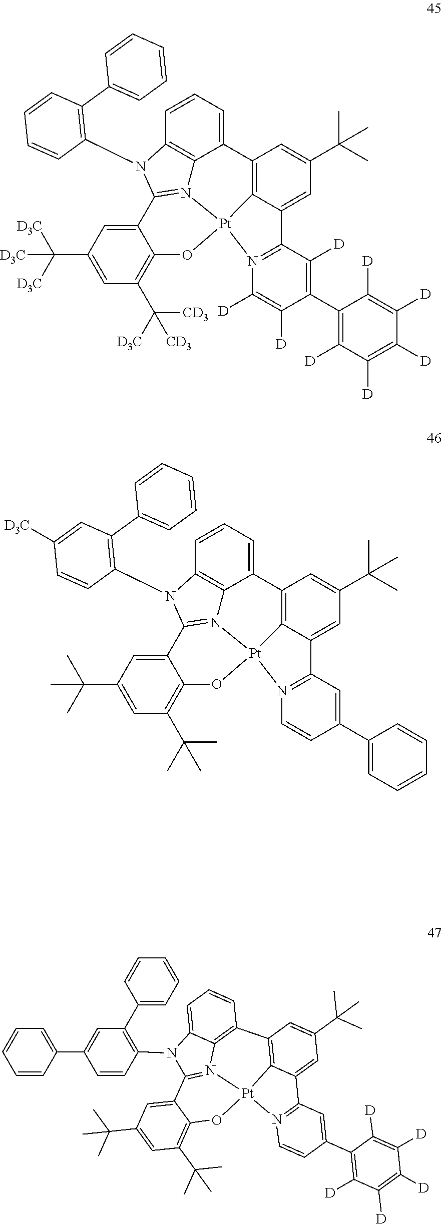

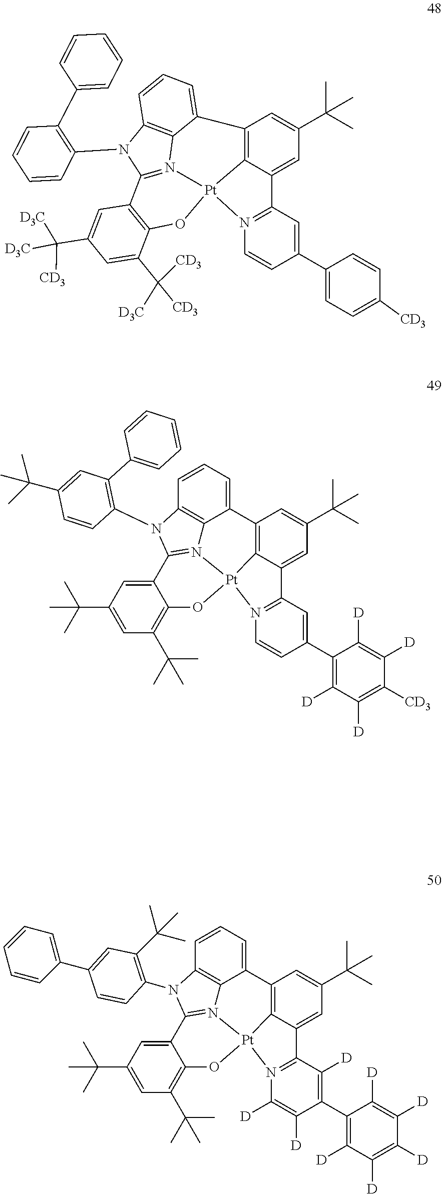

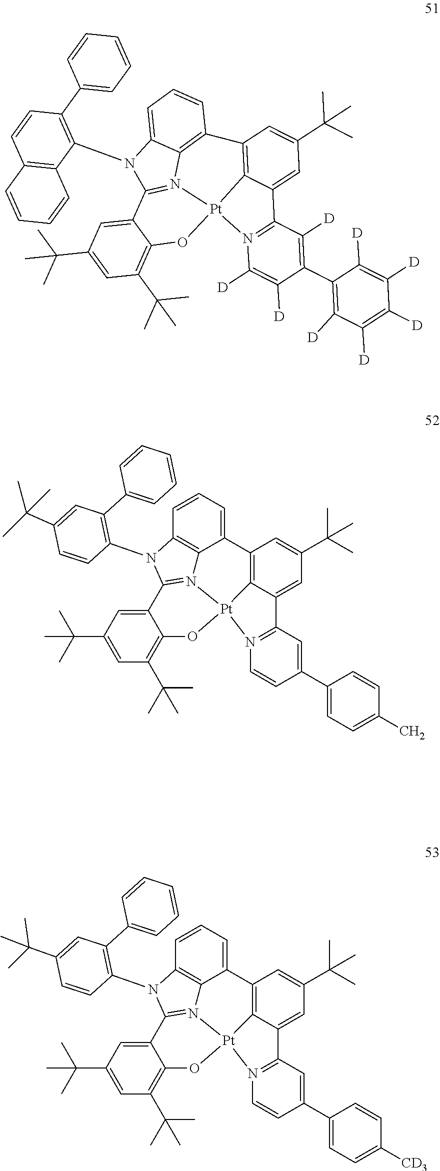

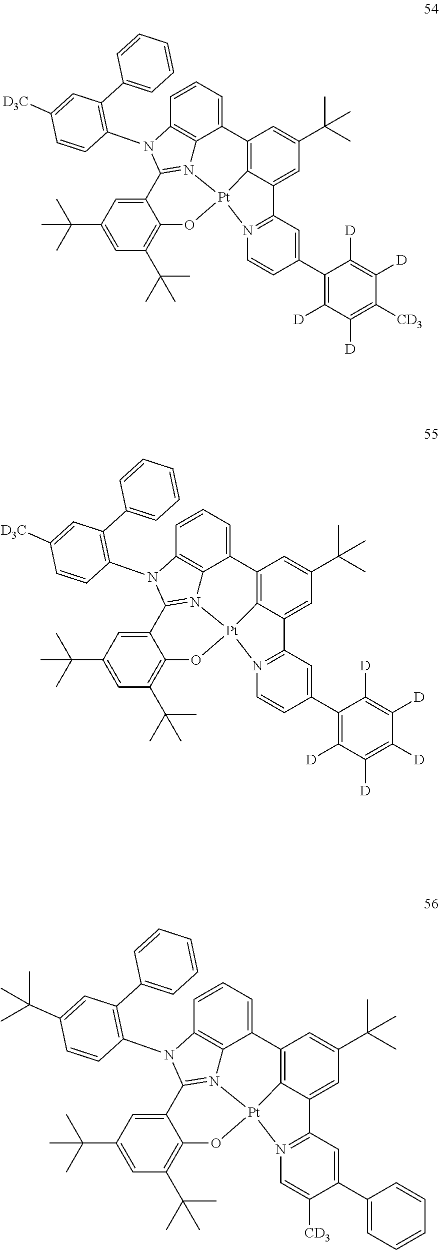

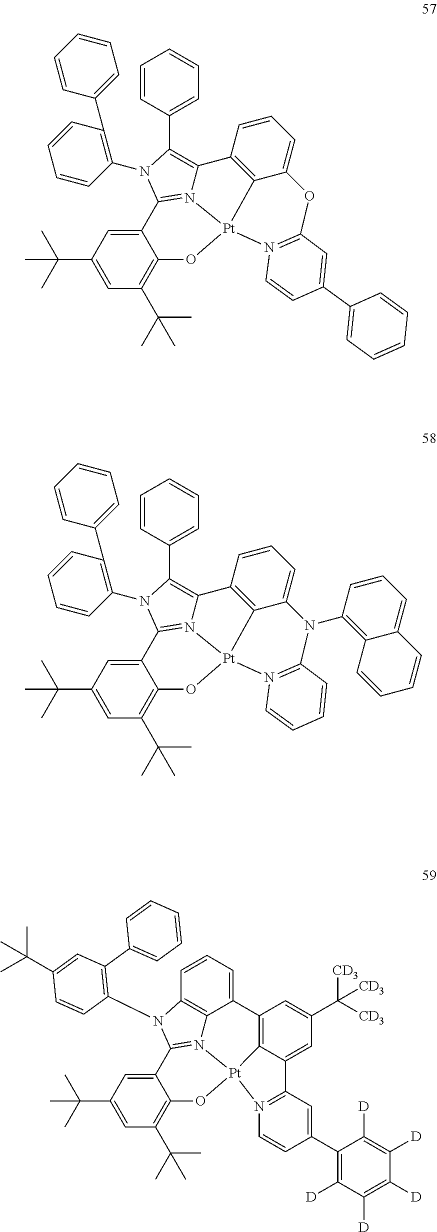

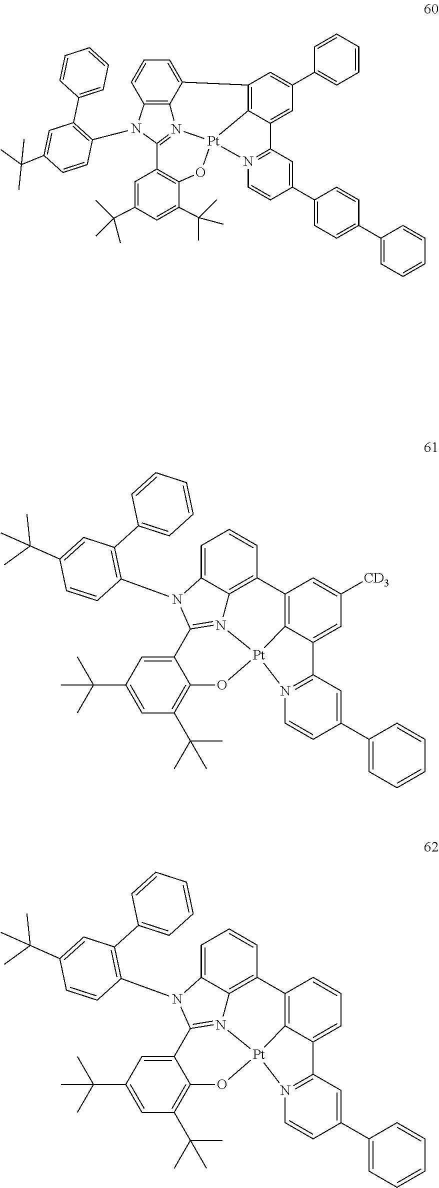

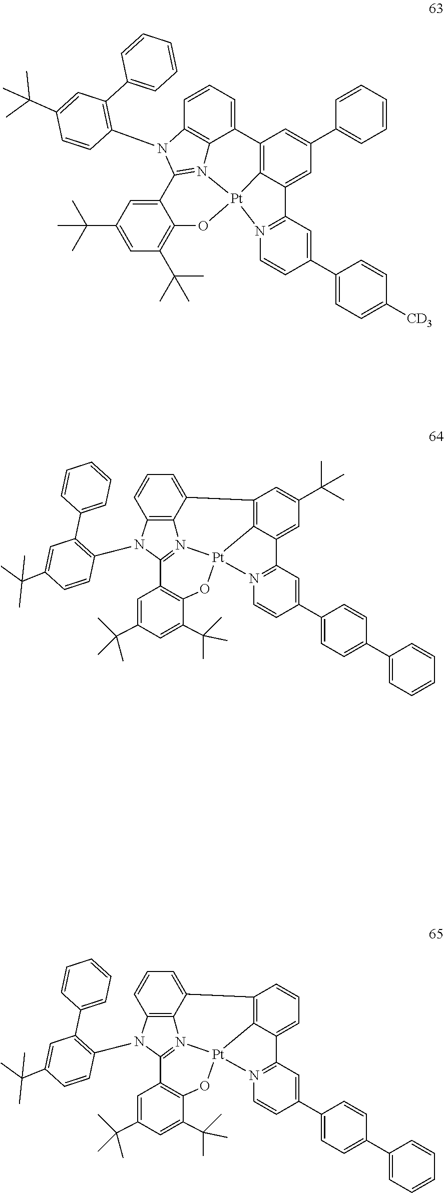

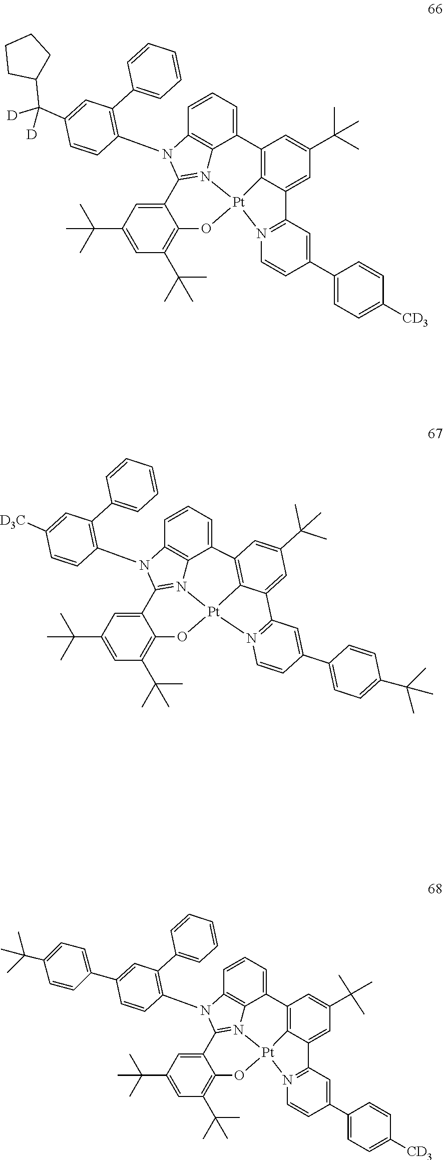

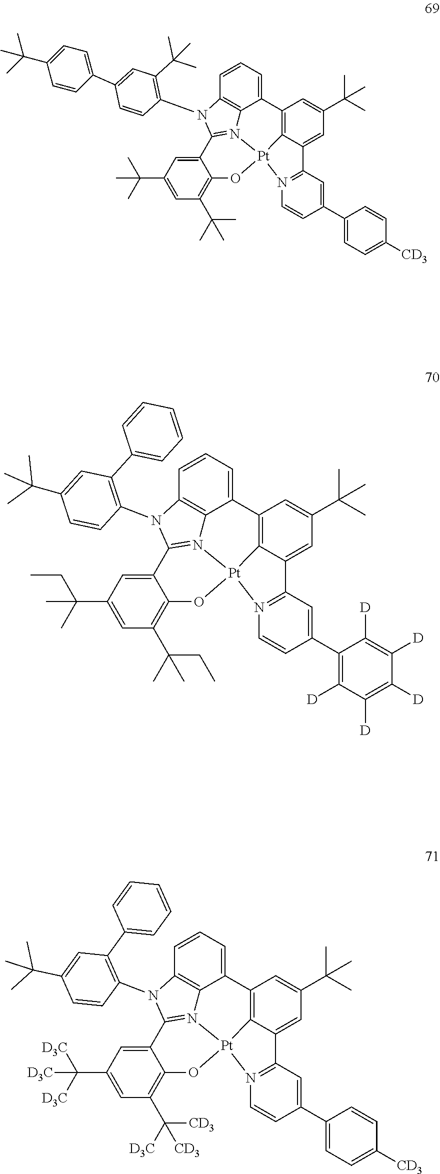

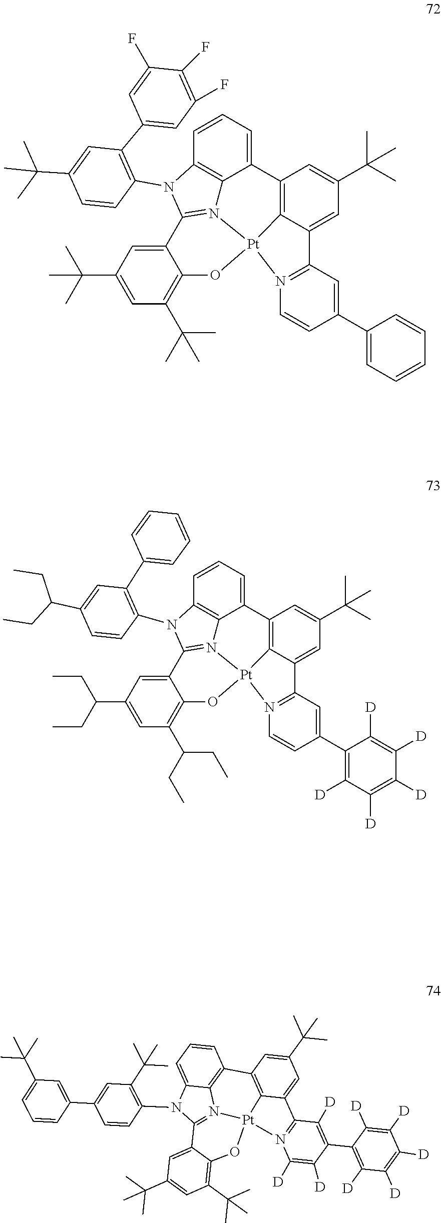

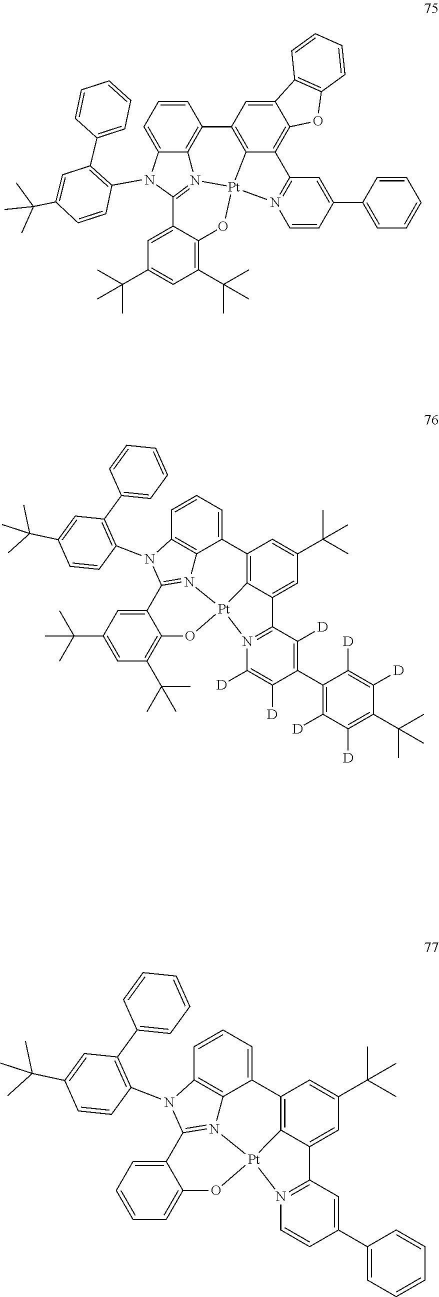

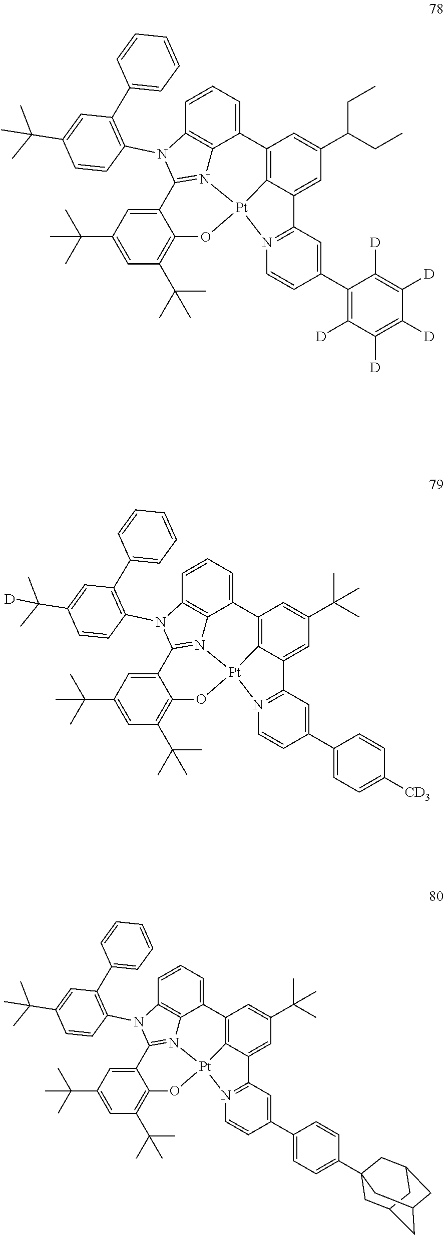

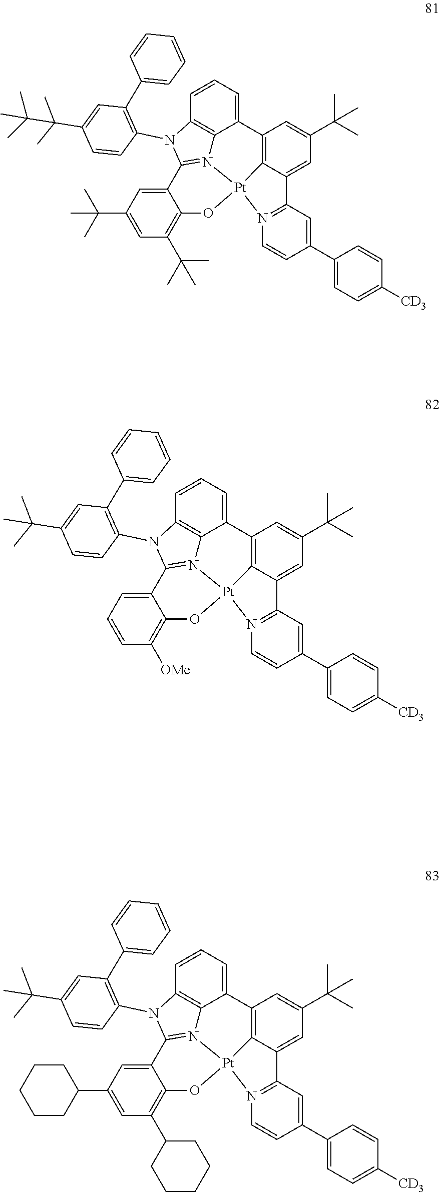

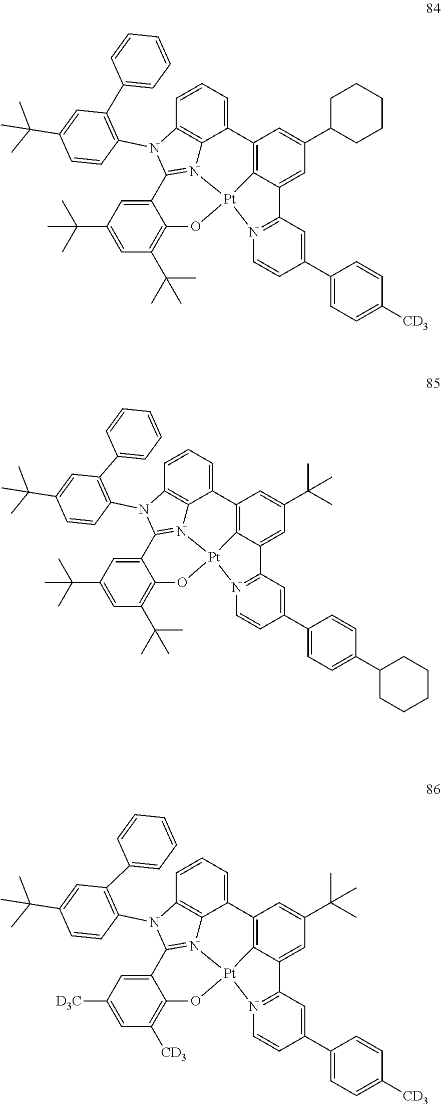

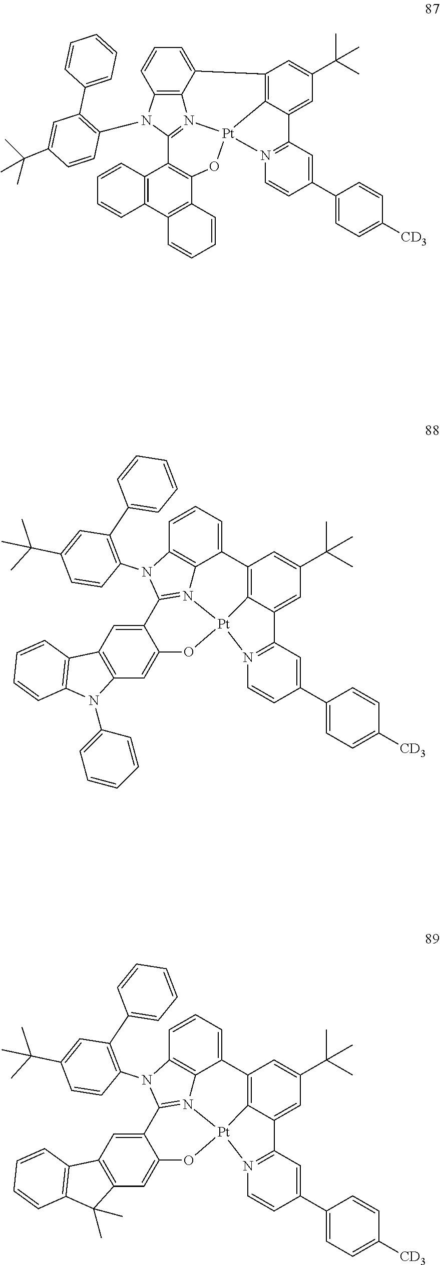

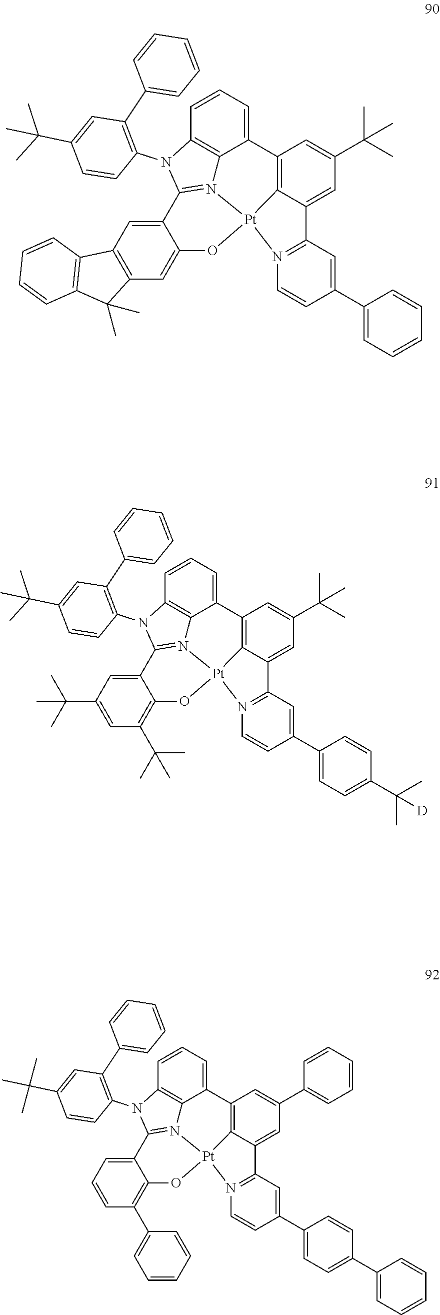

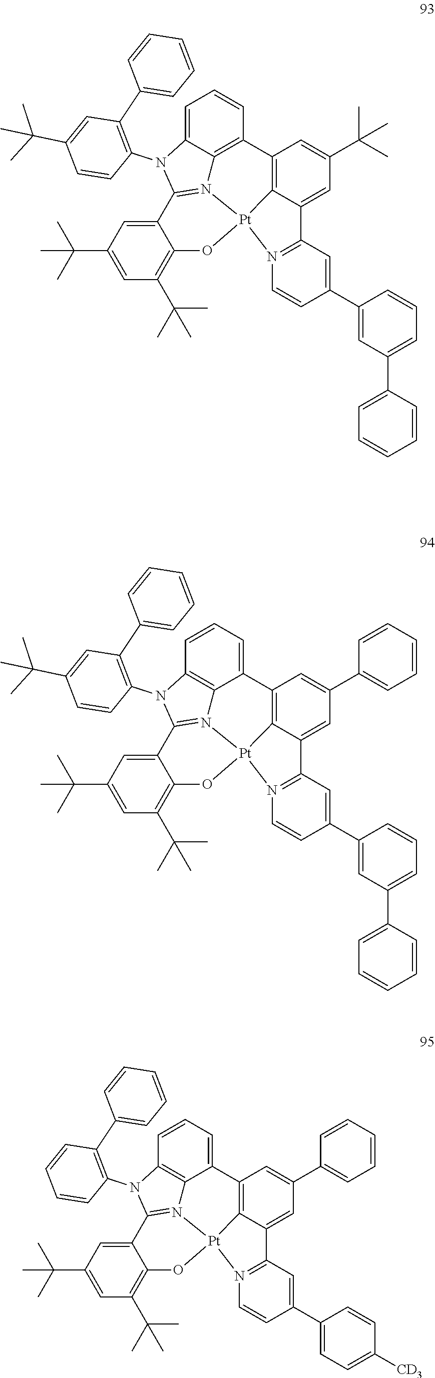

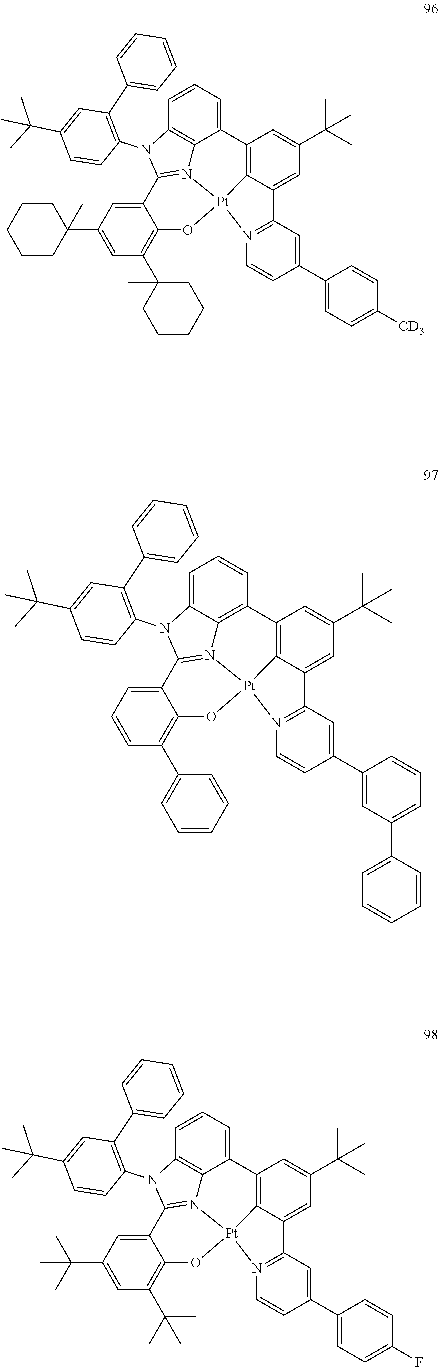

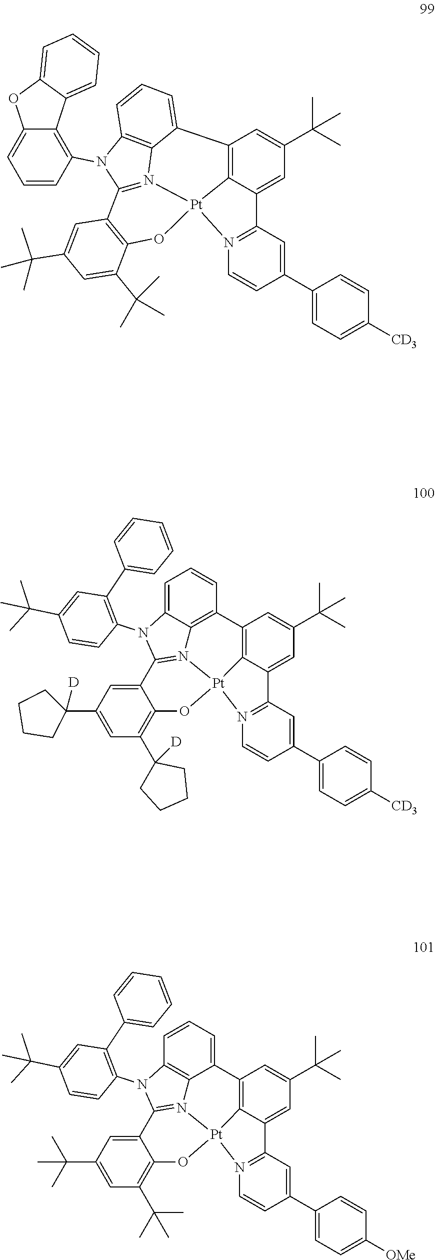

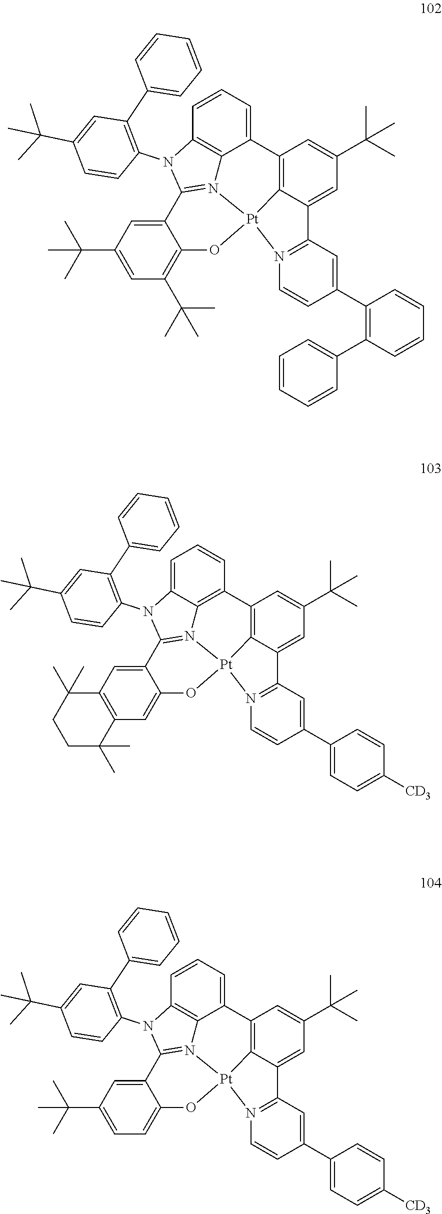

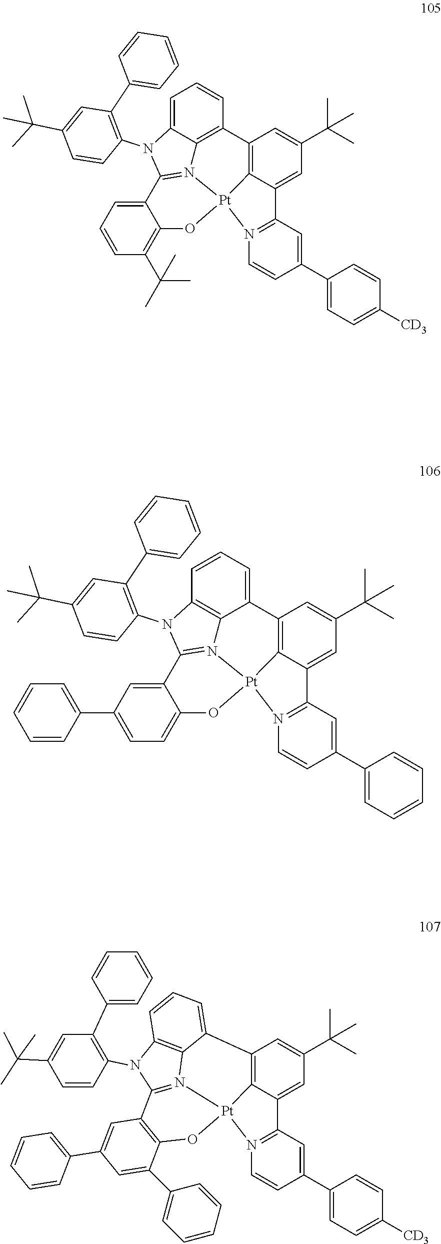

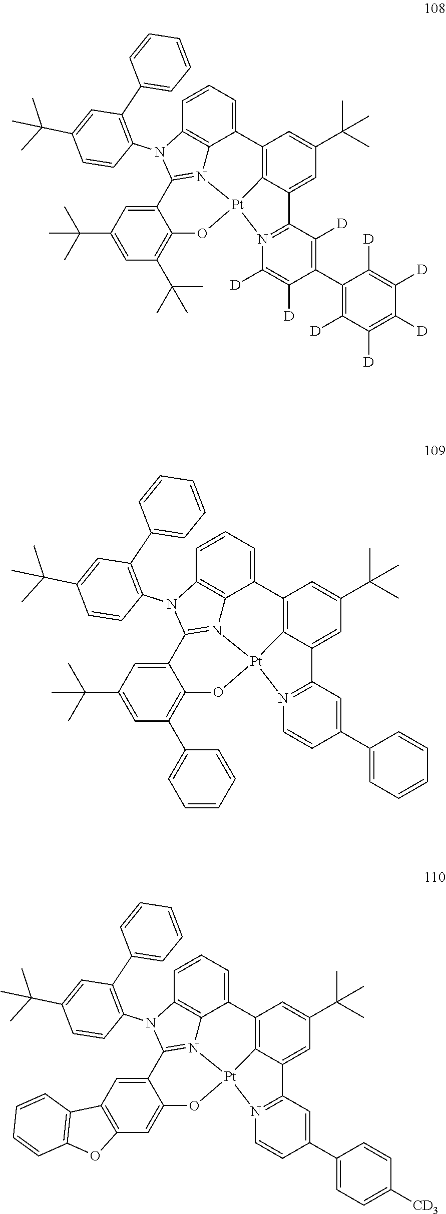

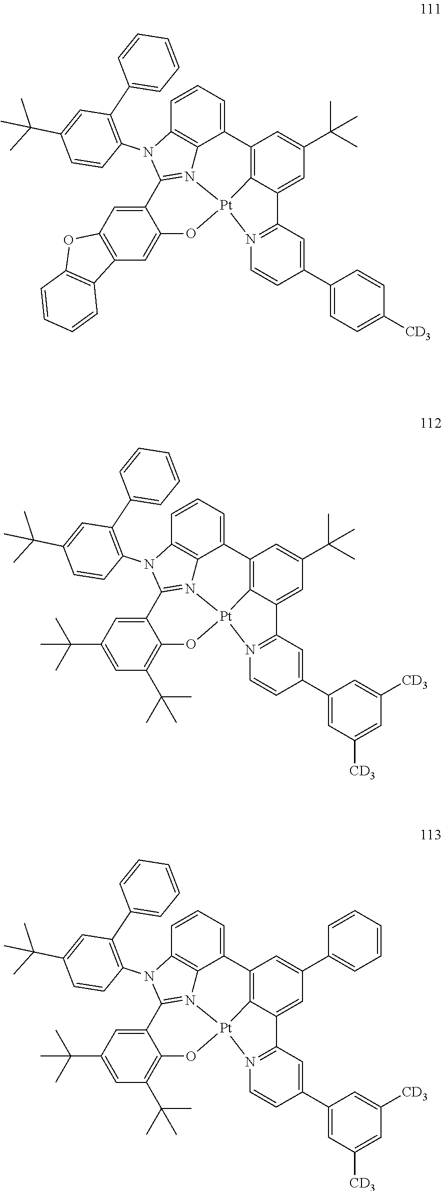

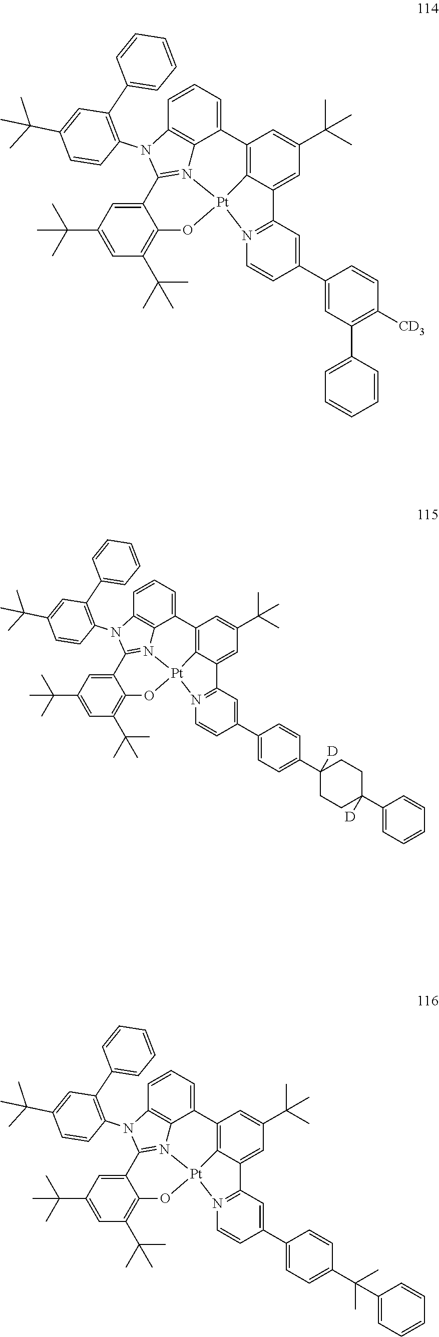

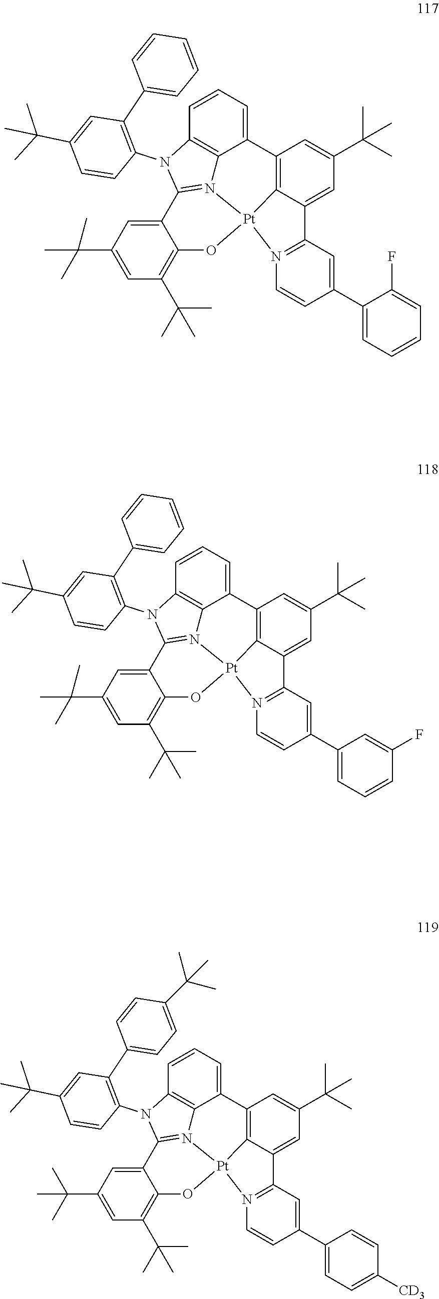

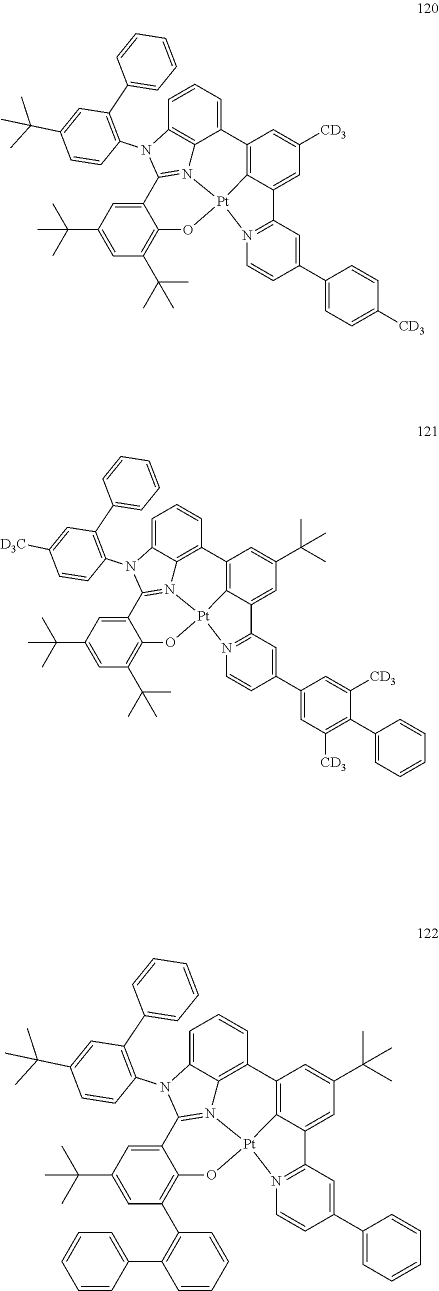

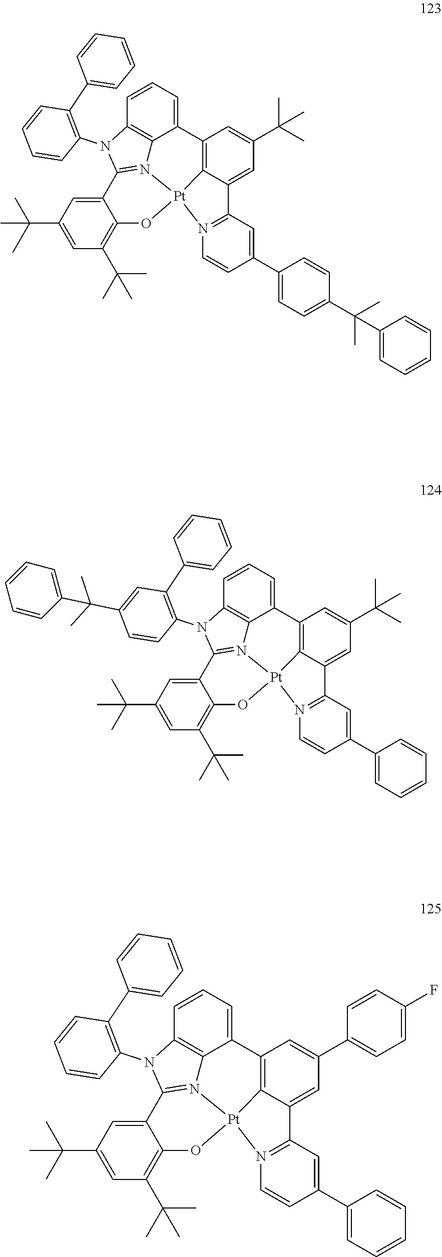

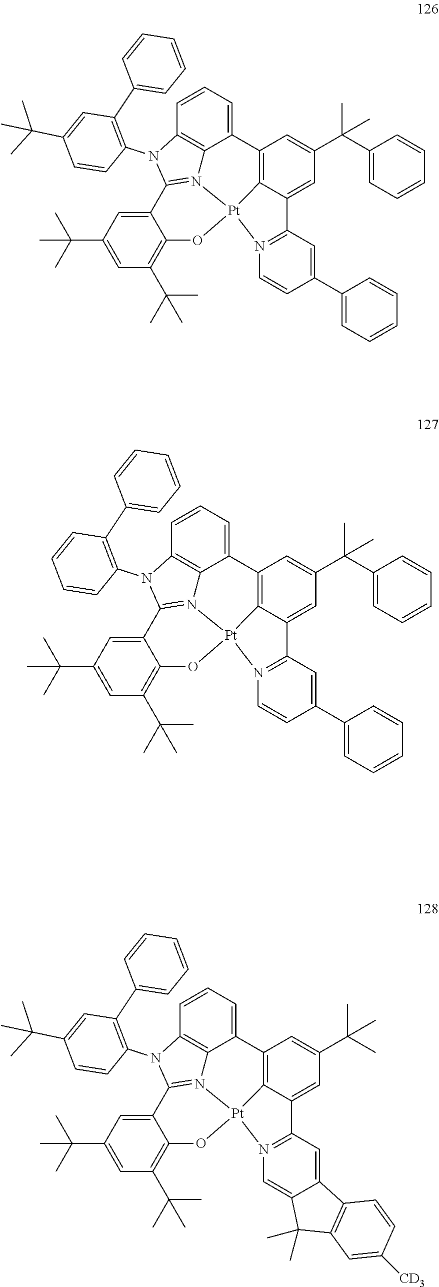

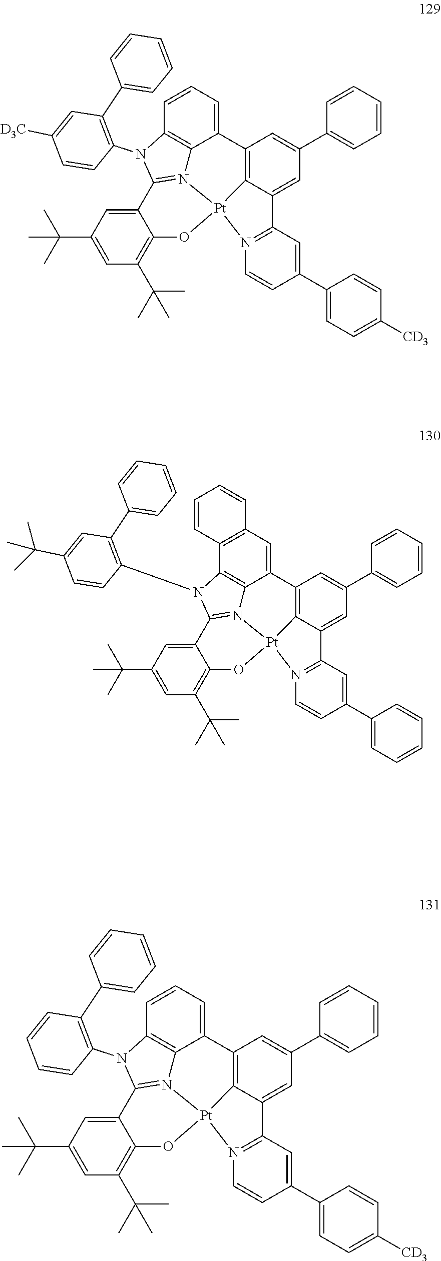

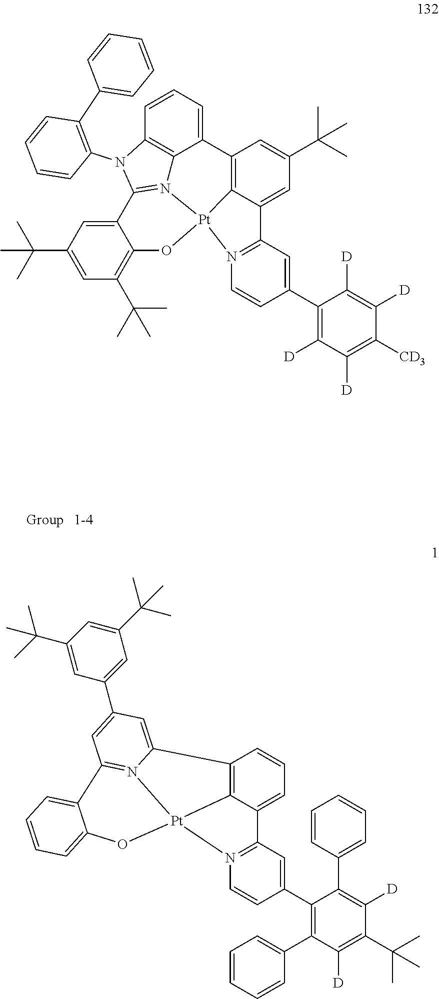

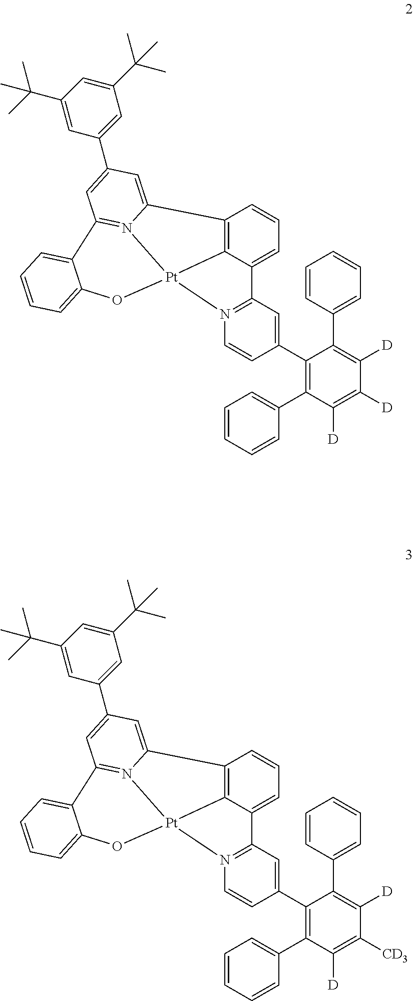

In one or more embodiments, the iridium-containing organometallic compound may be a compound of Group 2-1 to Group 2-6:

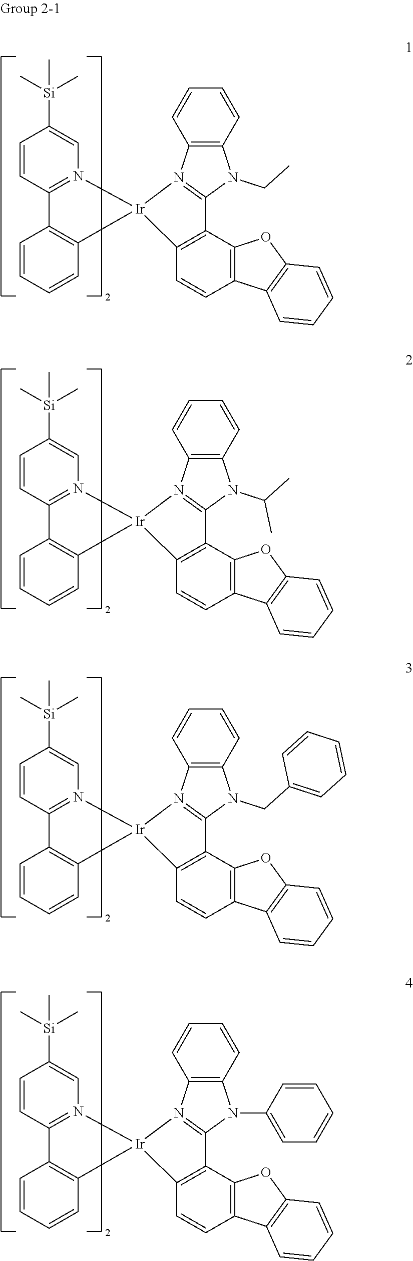

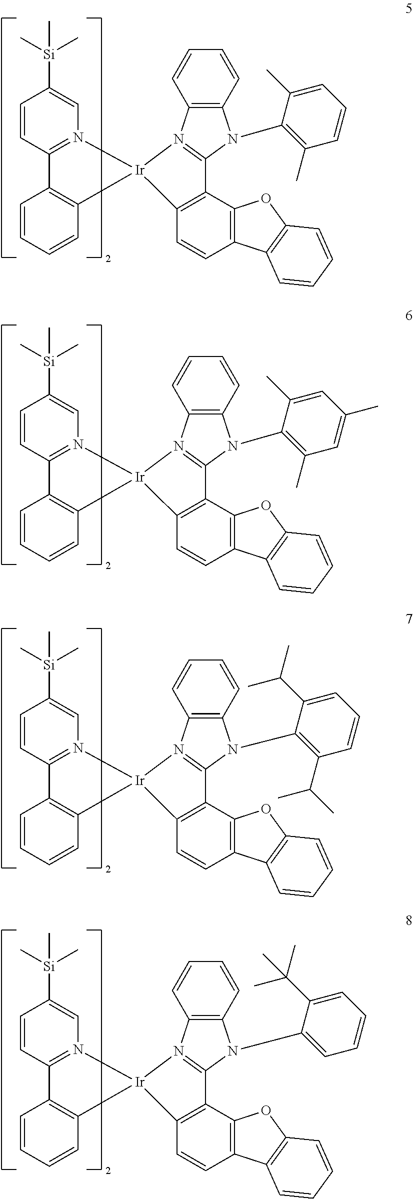

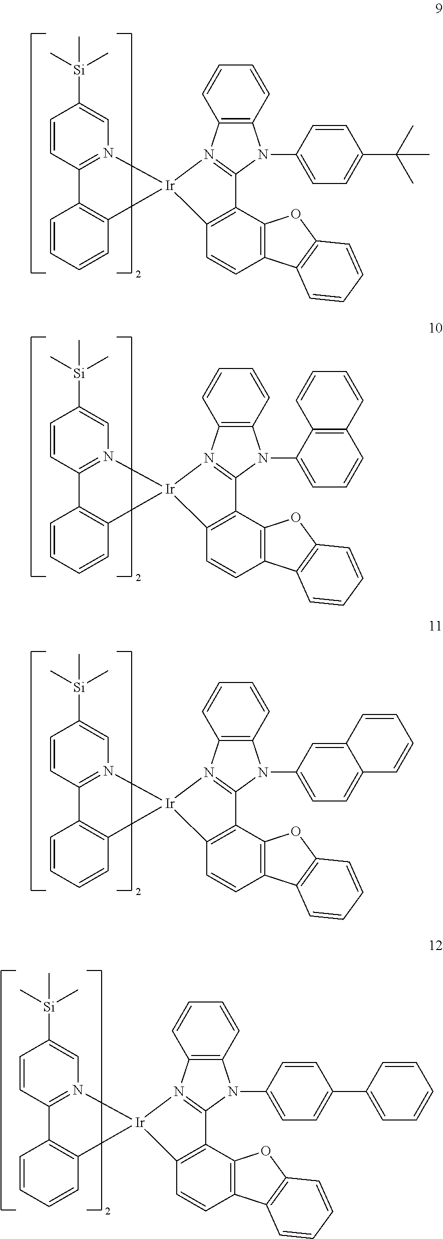

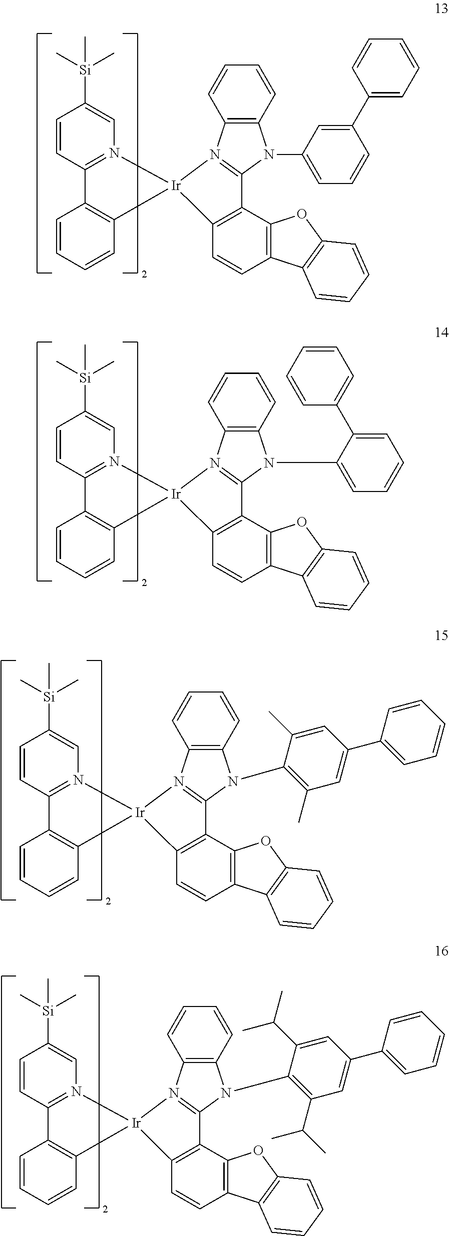

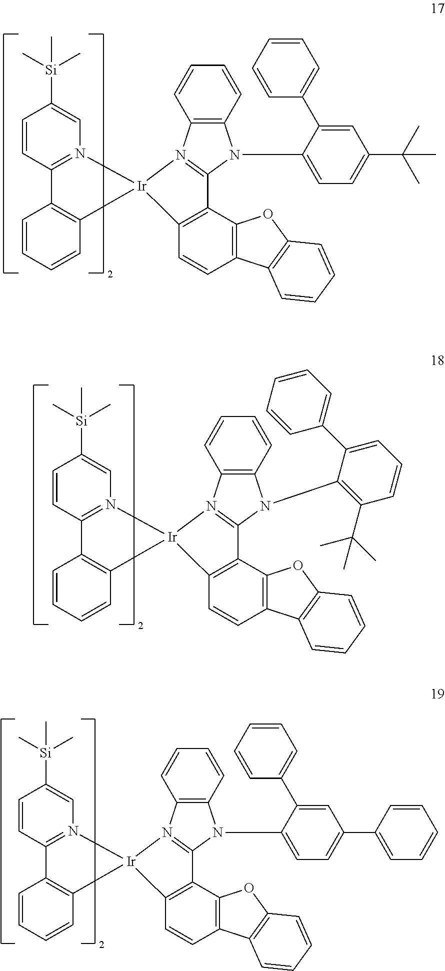

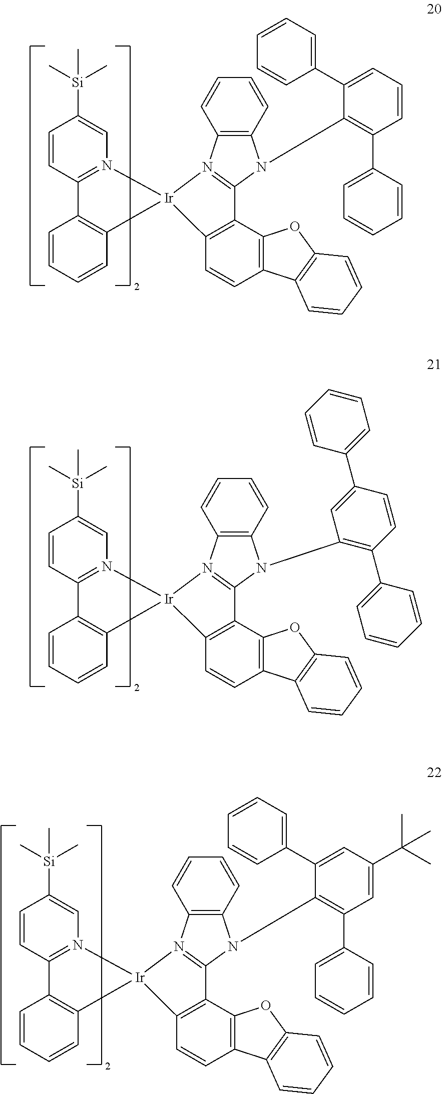

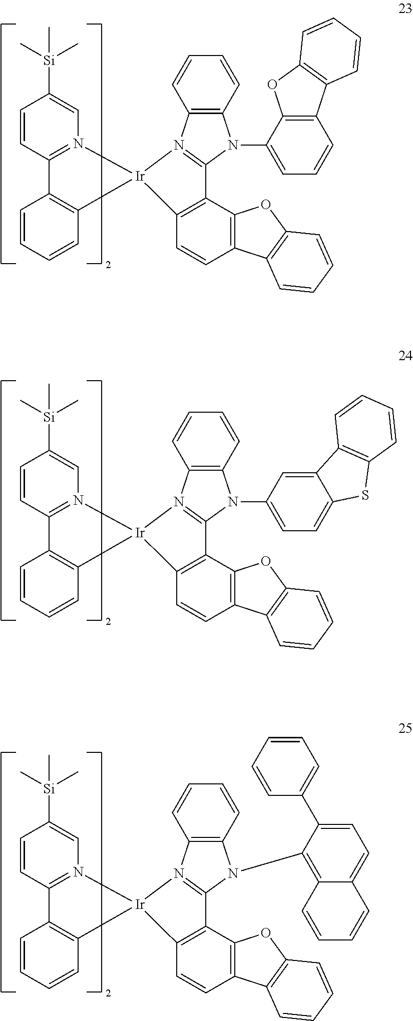

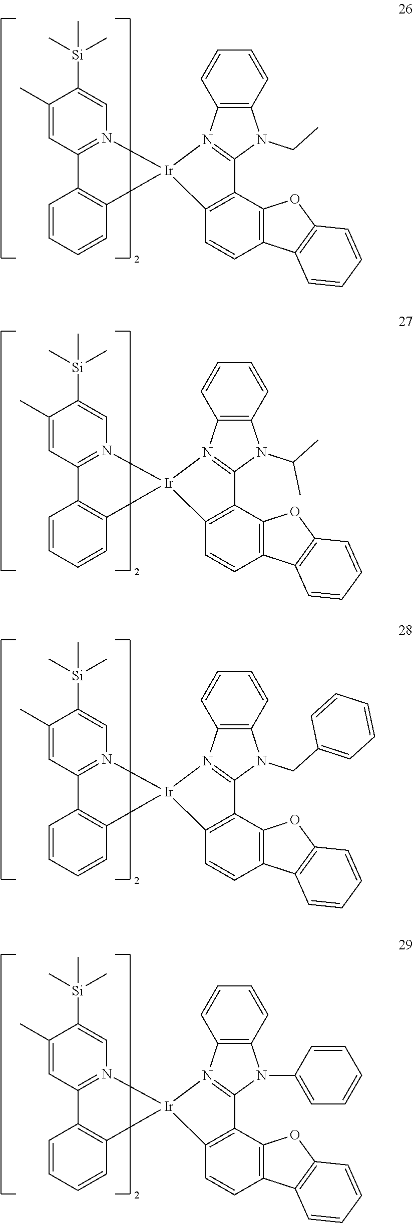

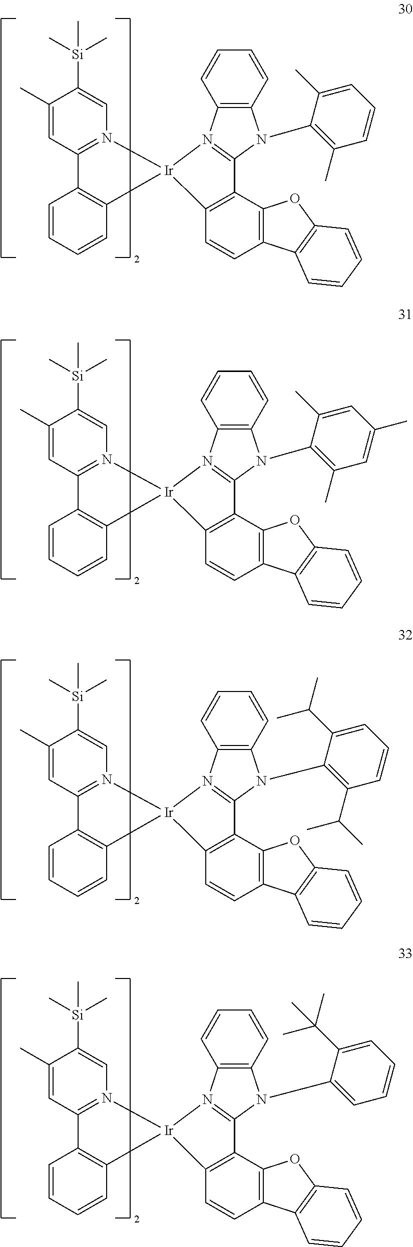

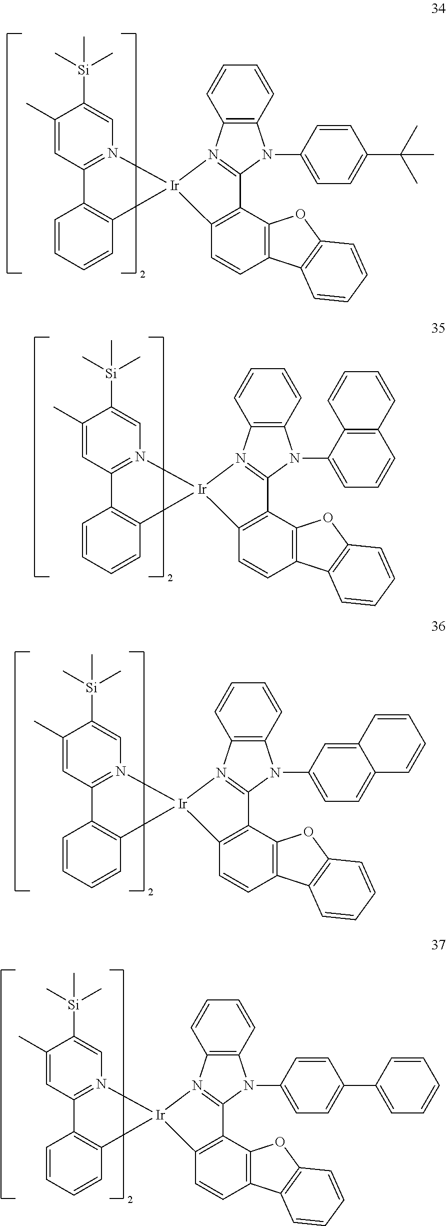

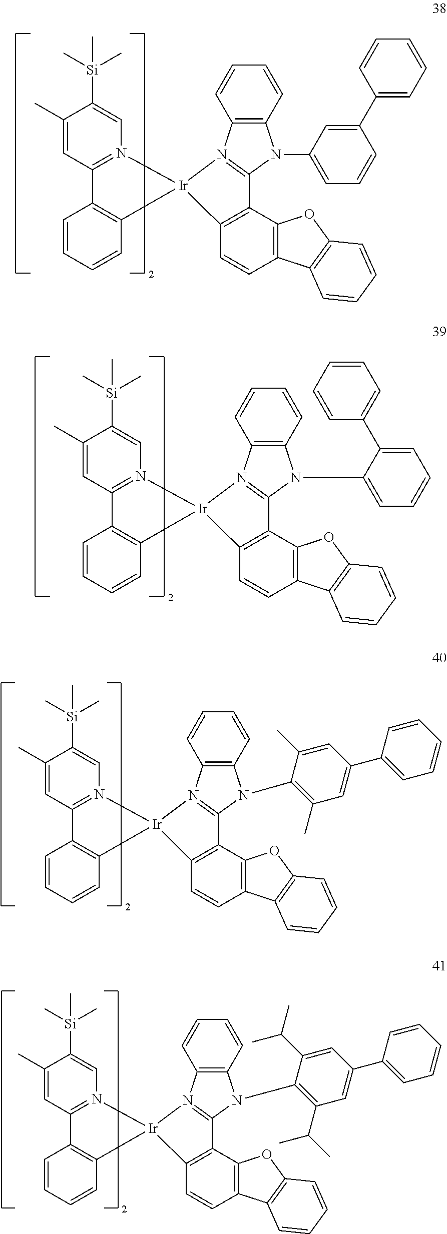

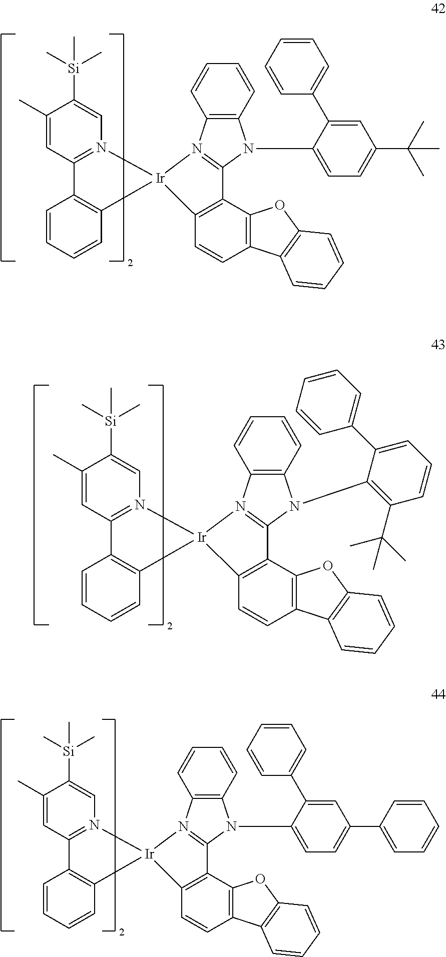

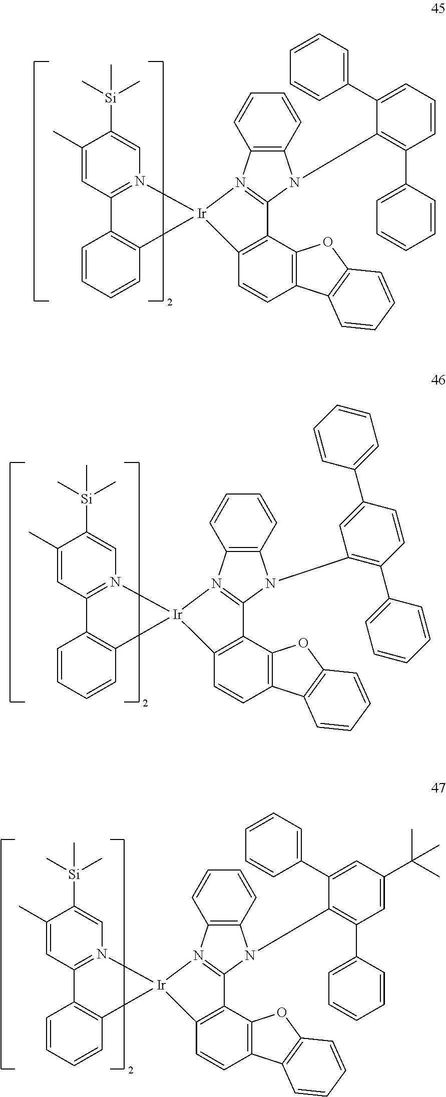

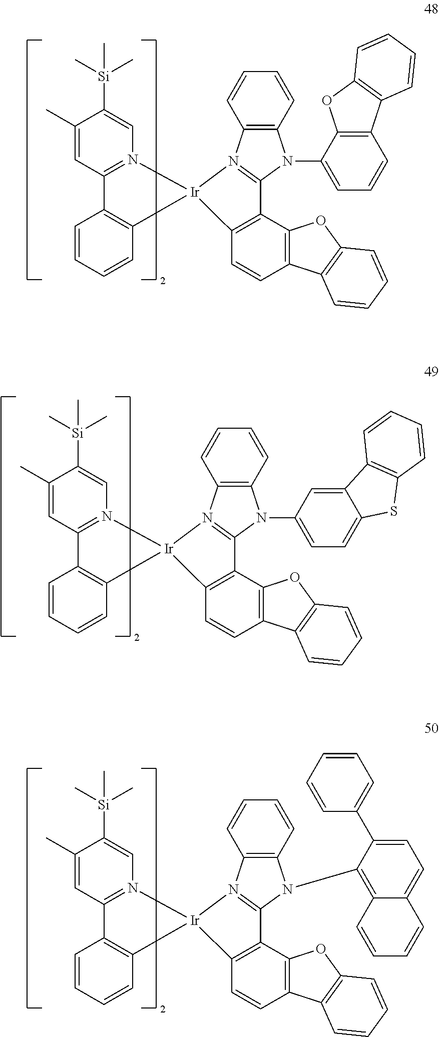

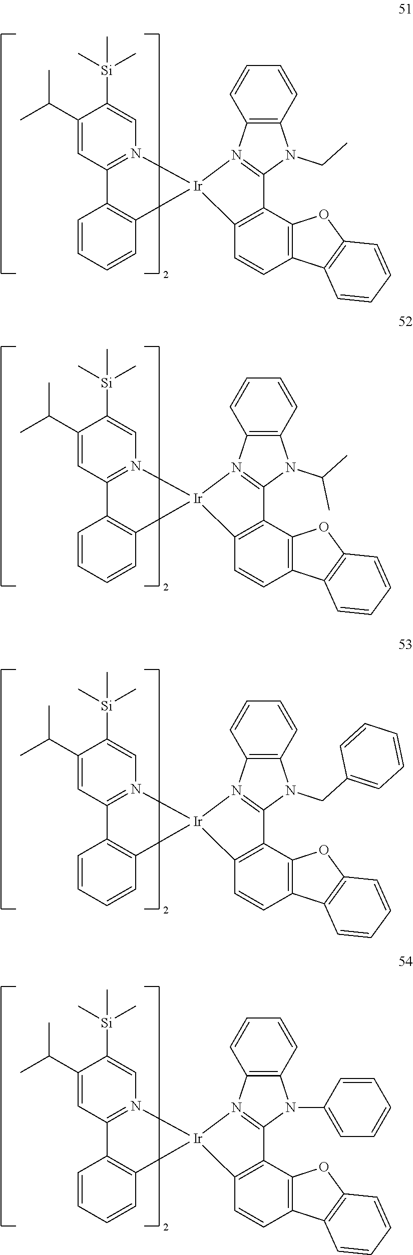

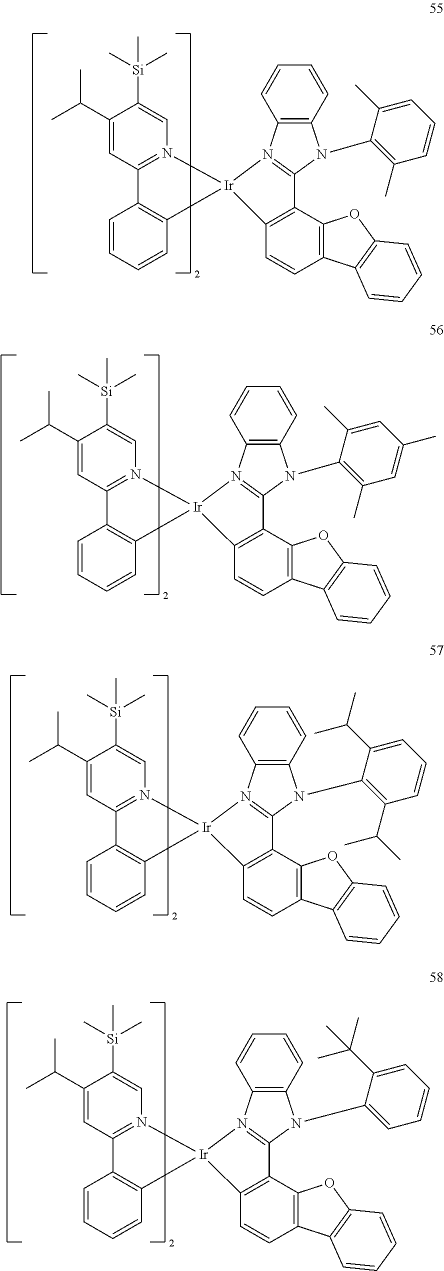

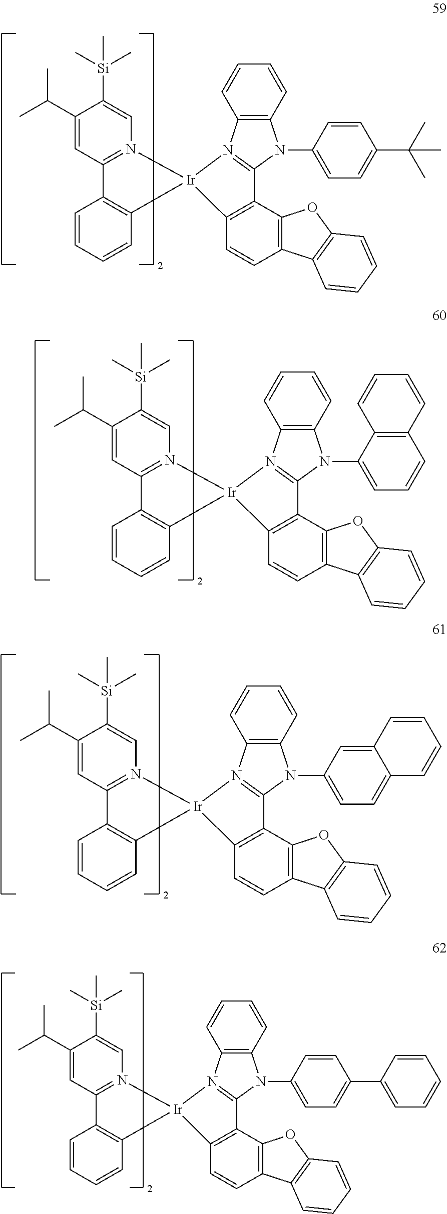

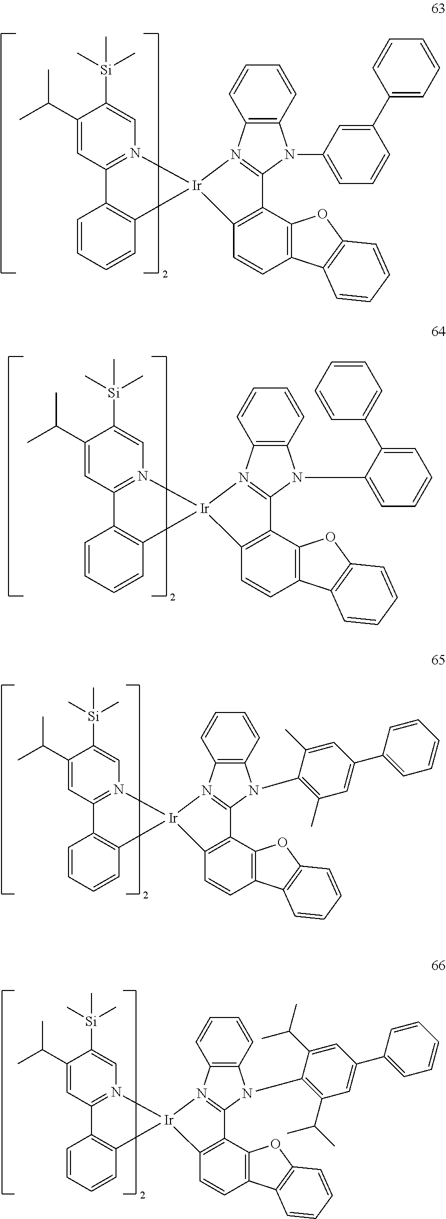

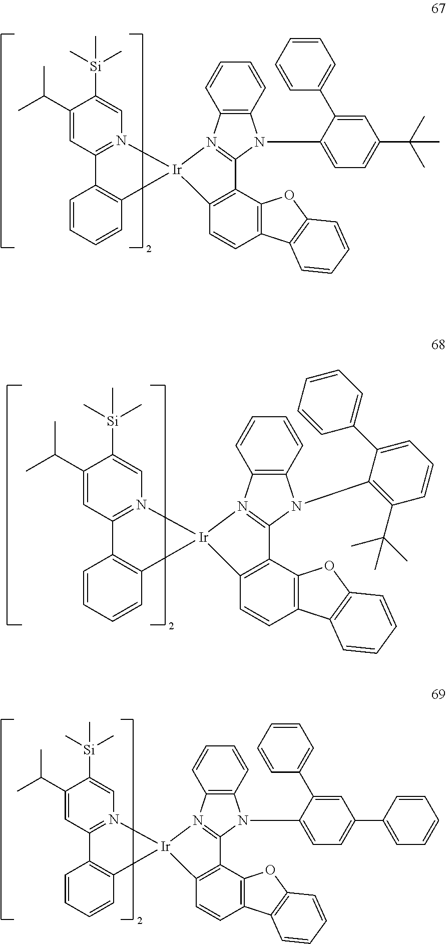

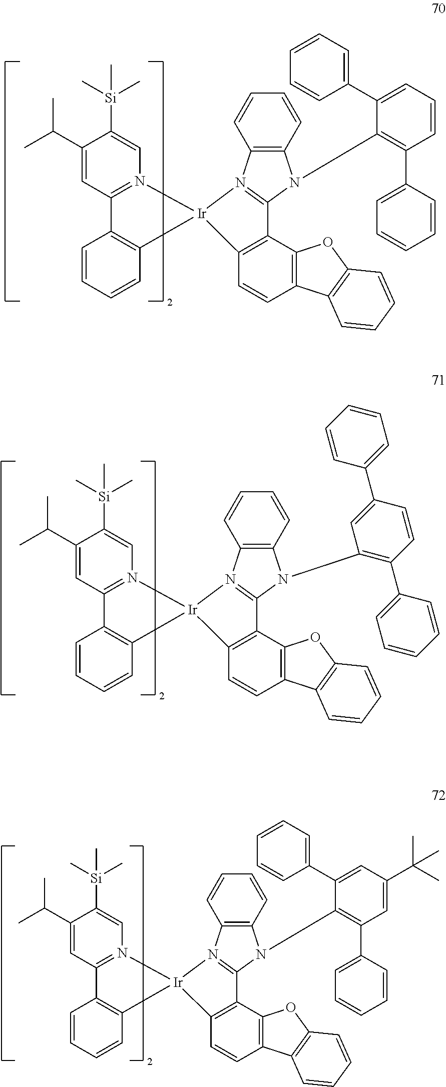

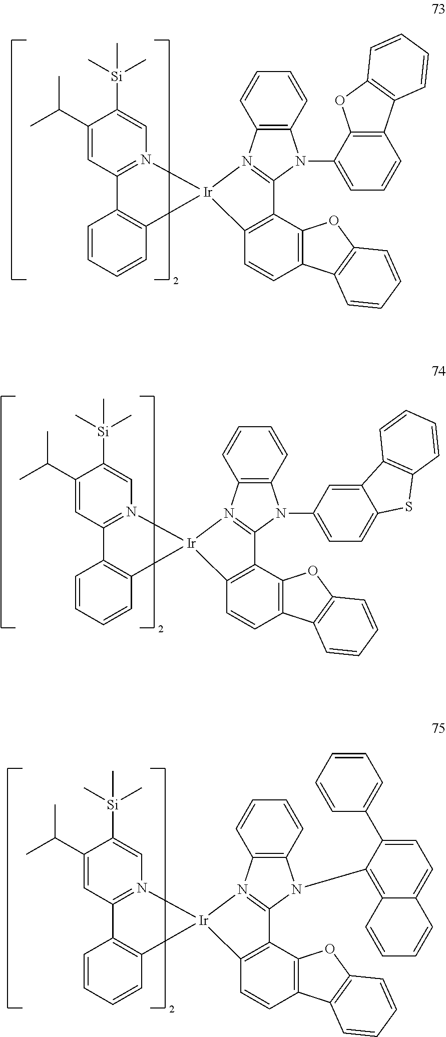

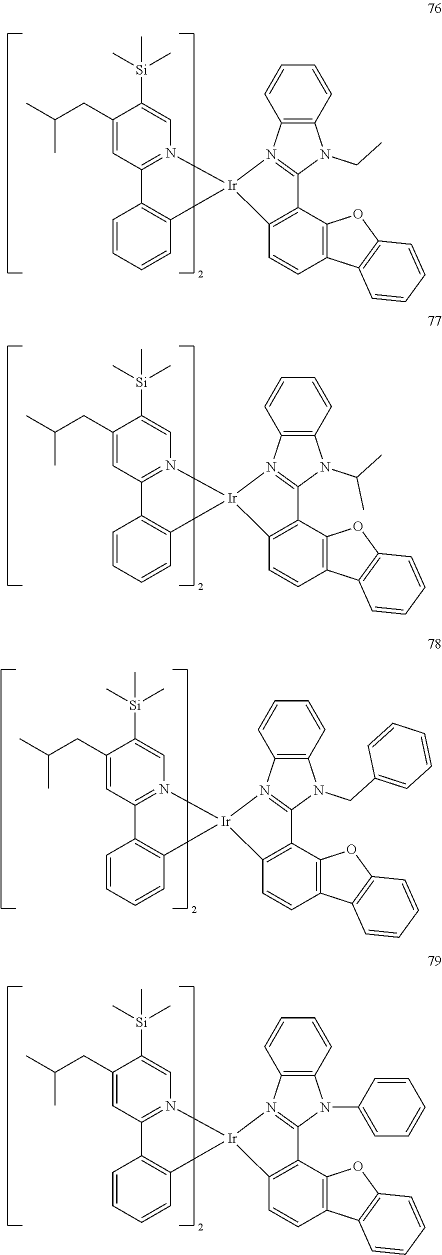

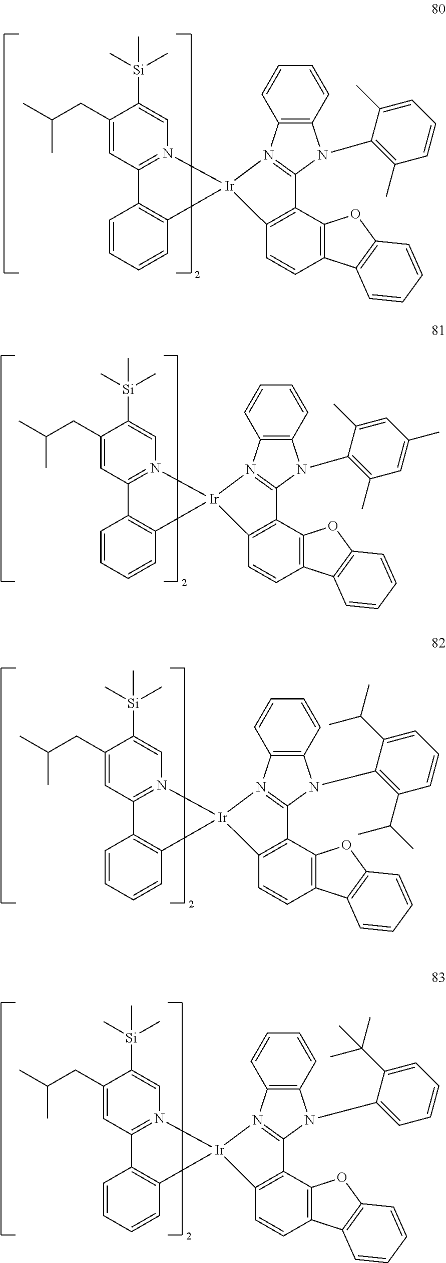

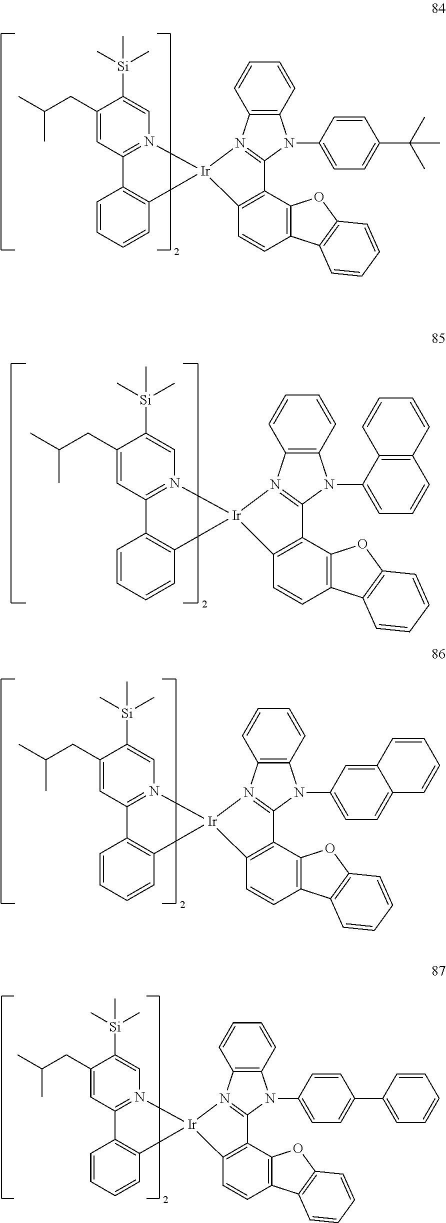

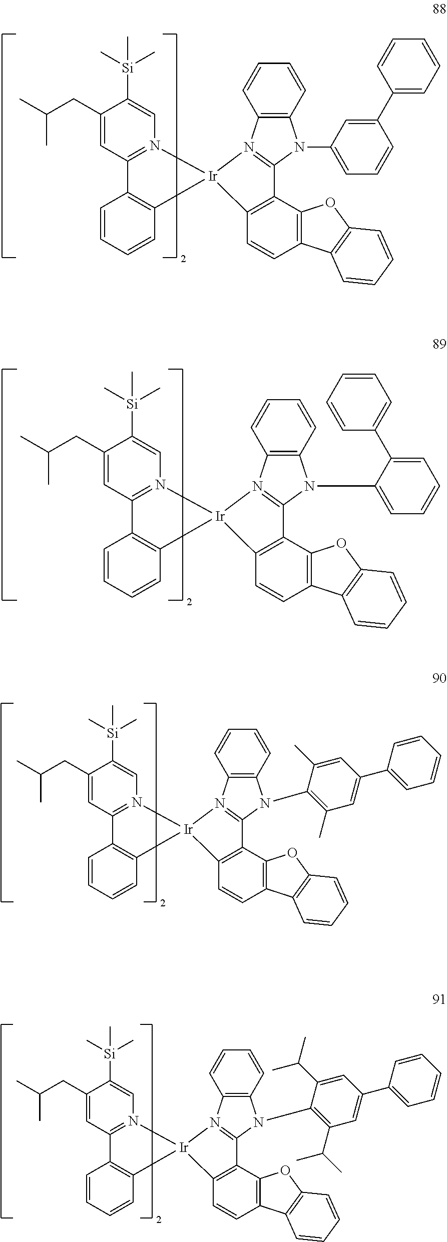

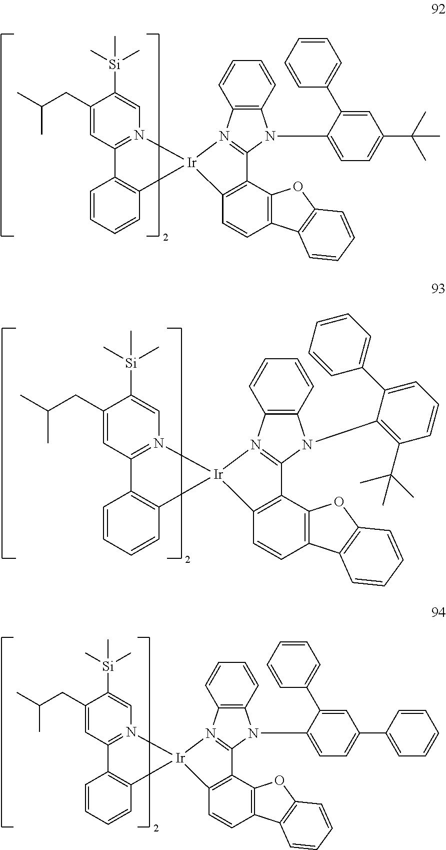

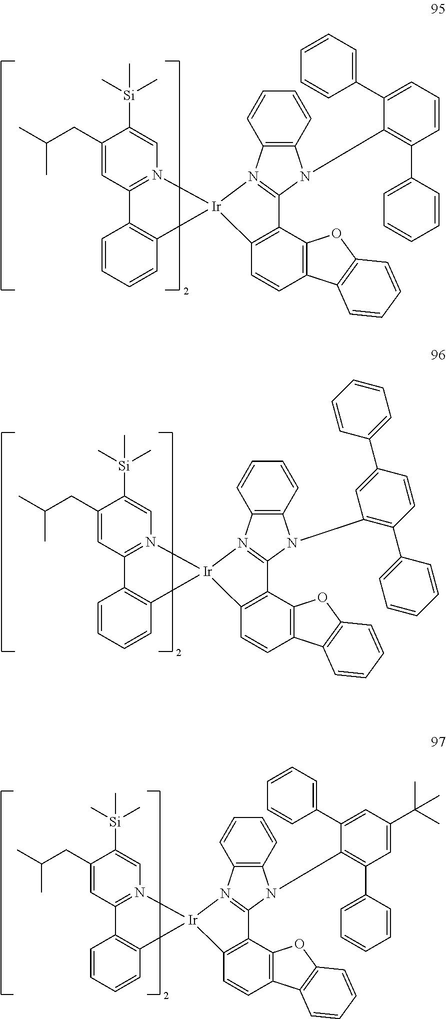

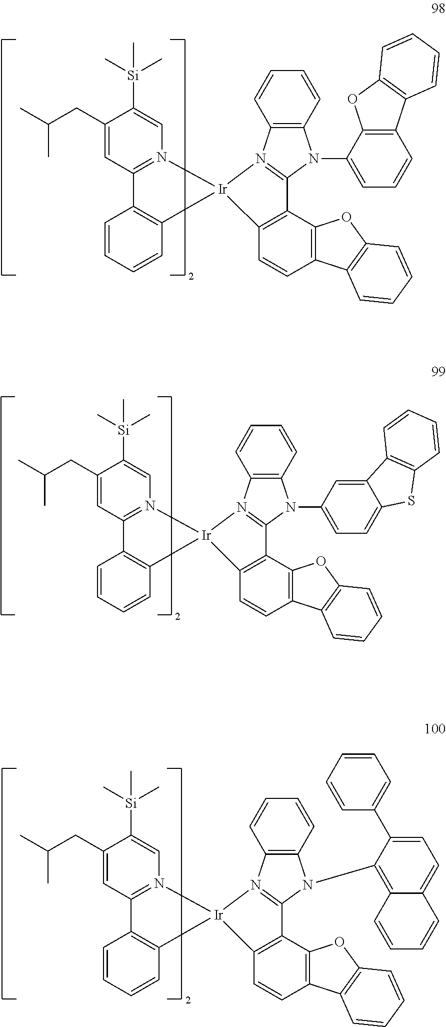

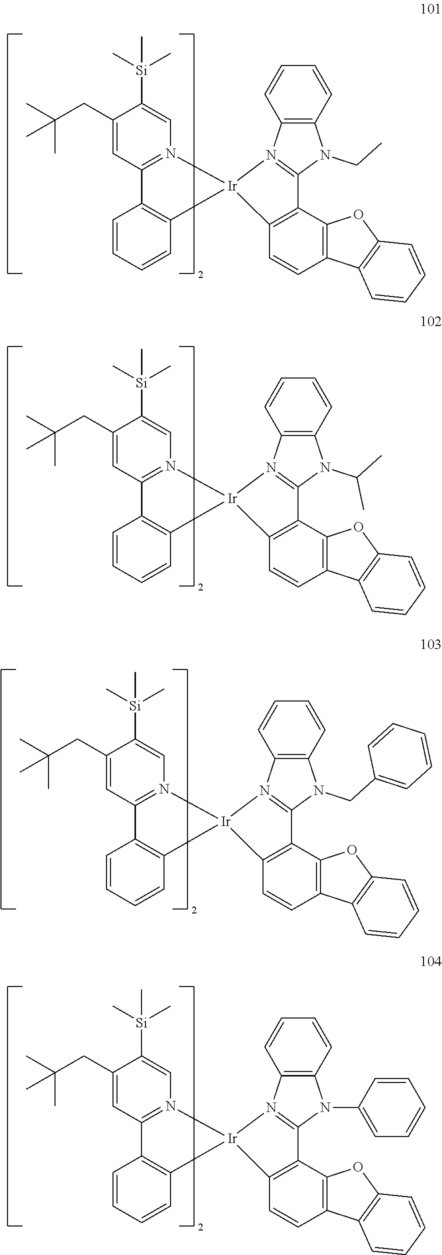

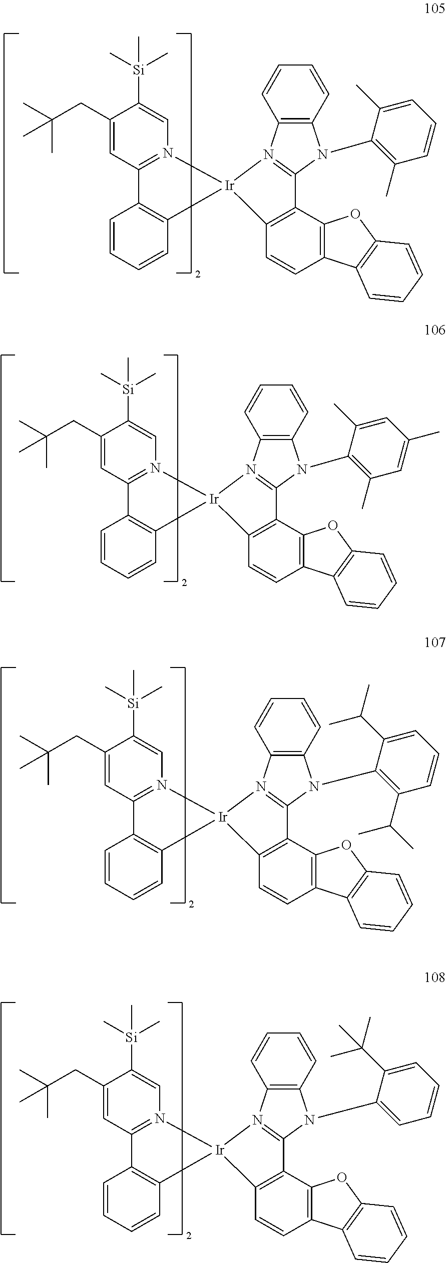

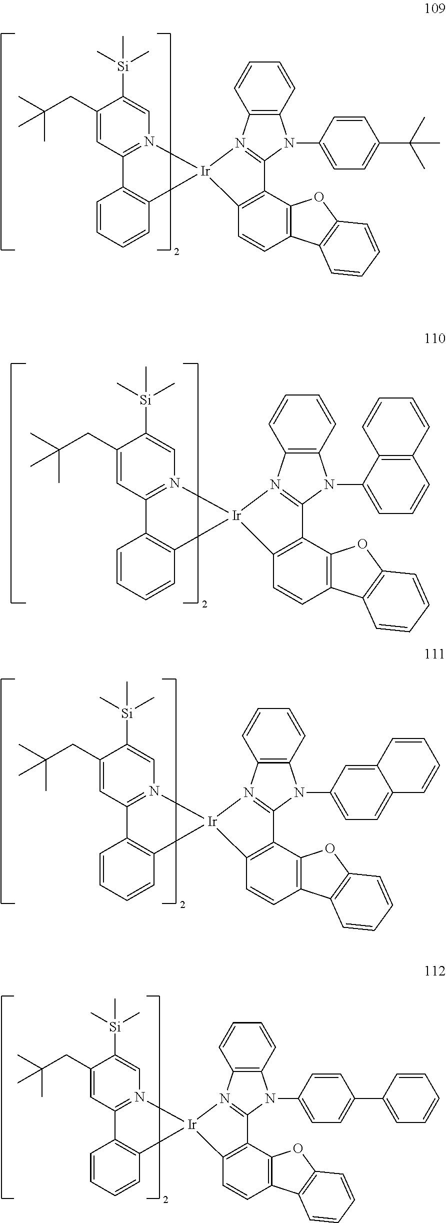

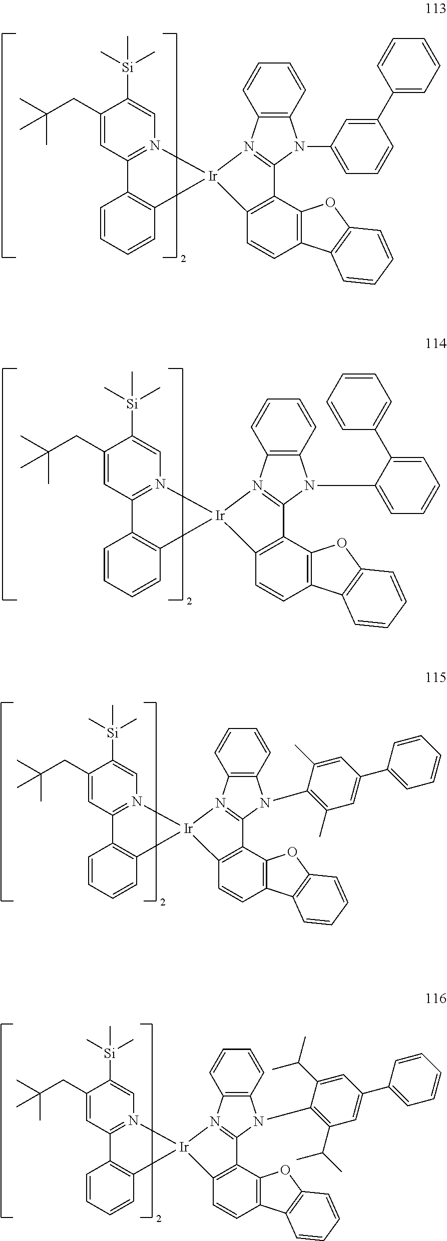

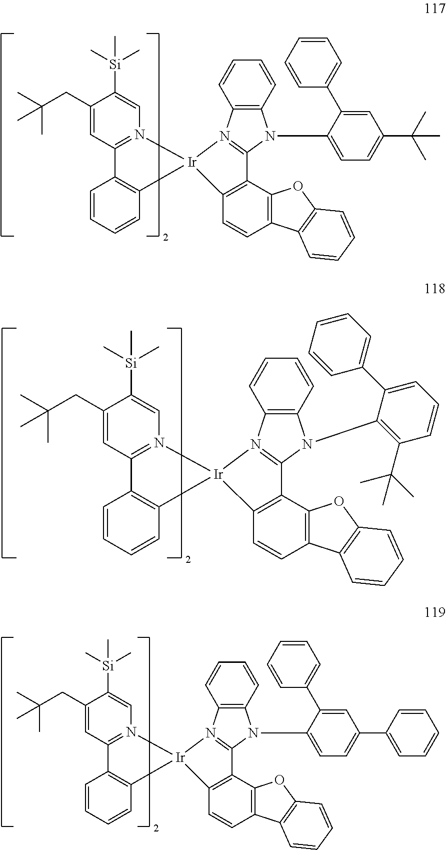

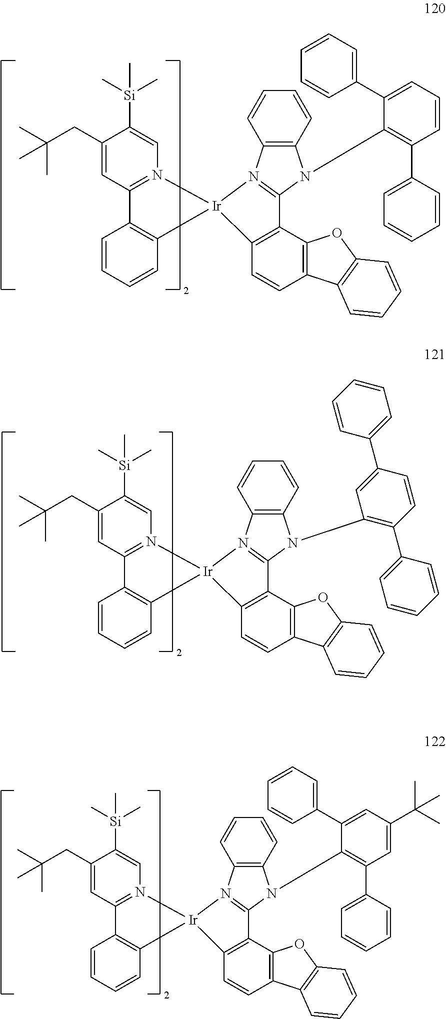

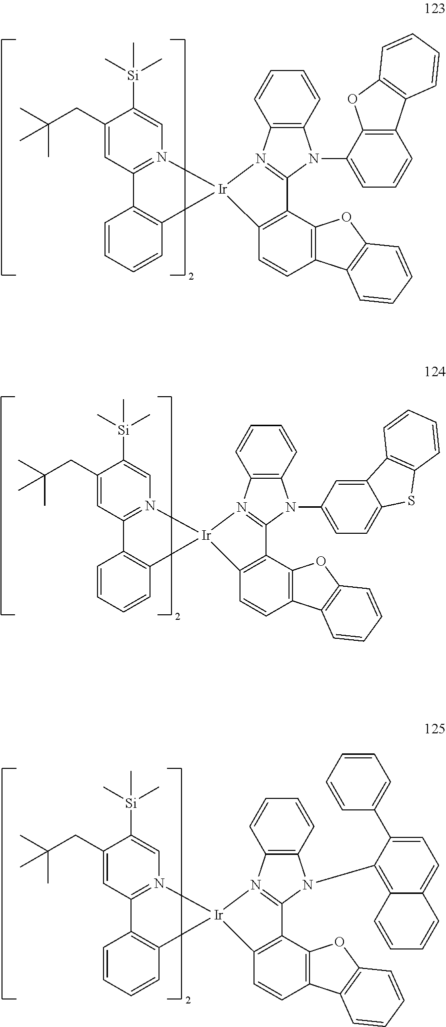

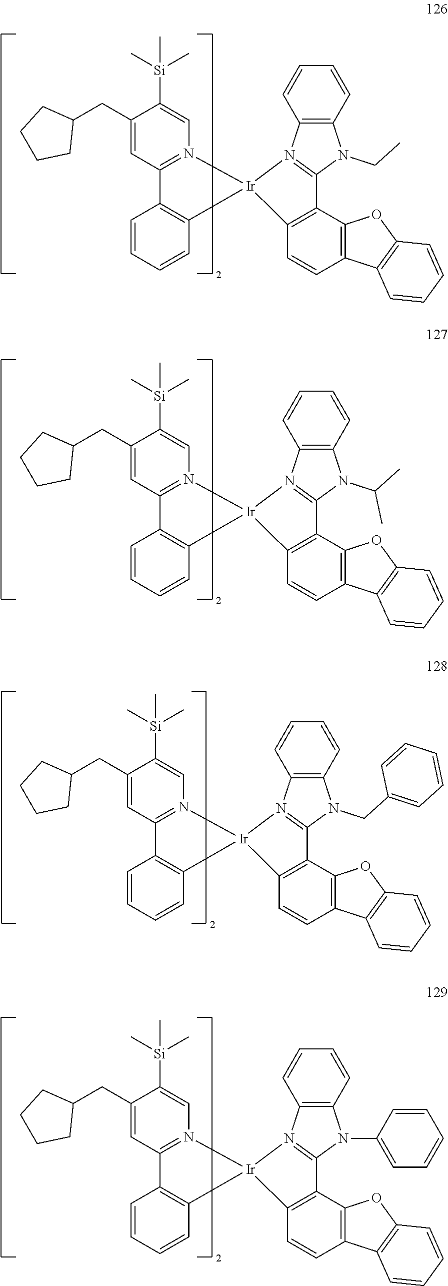

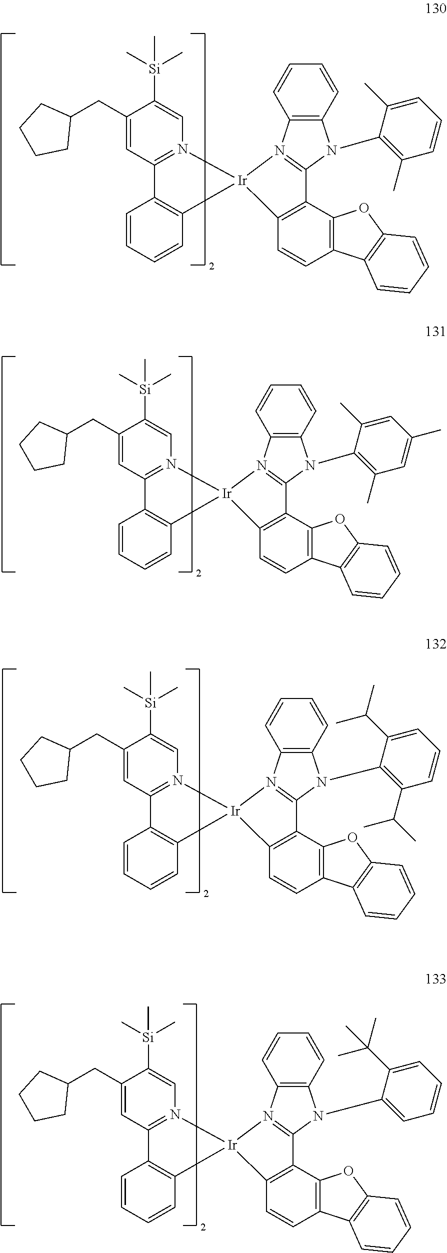

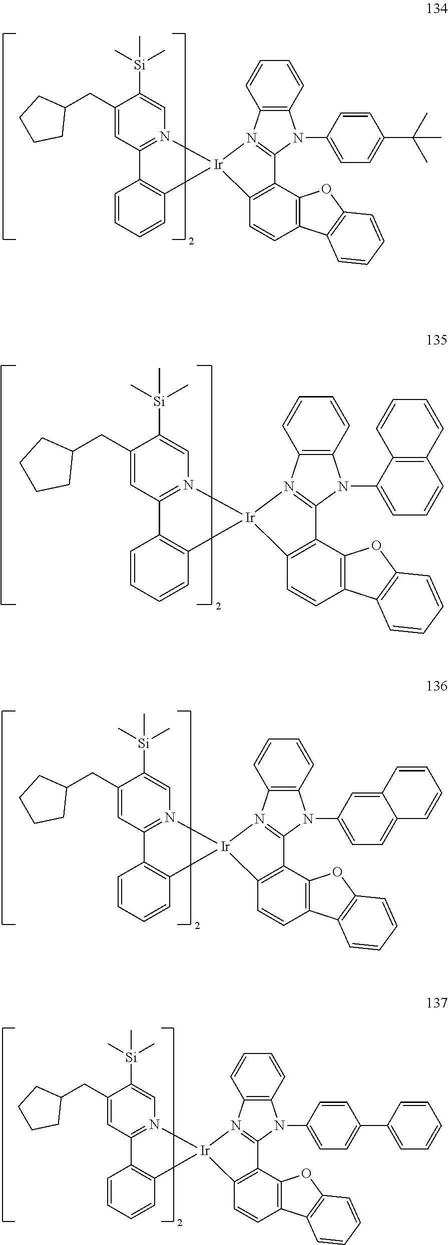

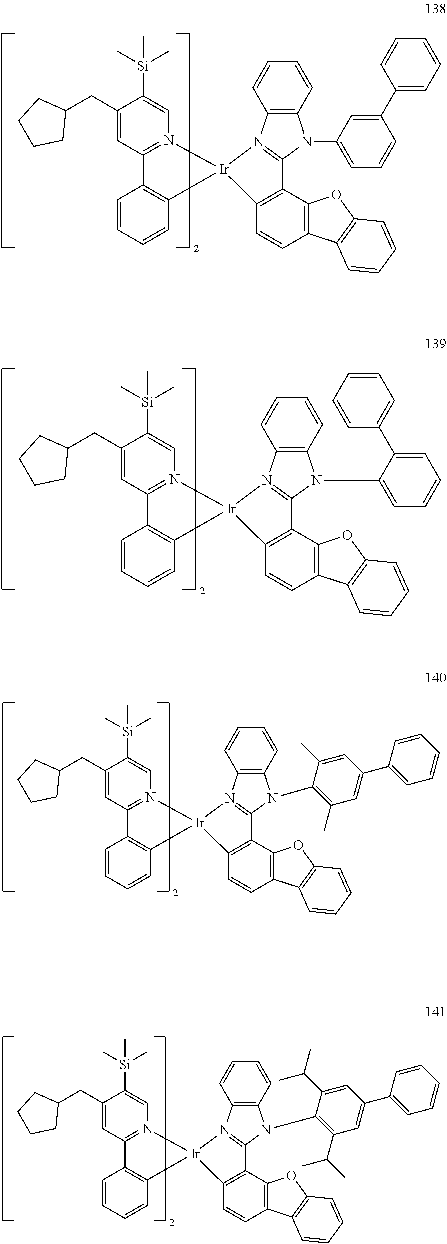

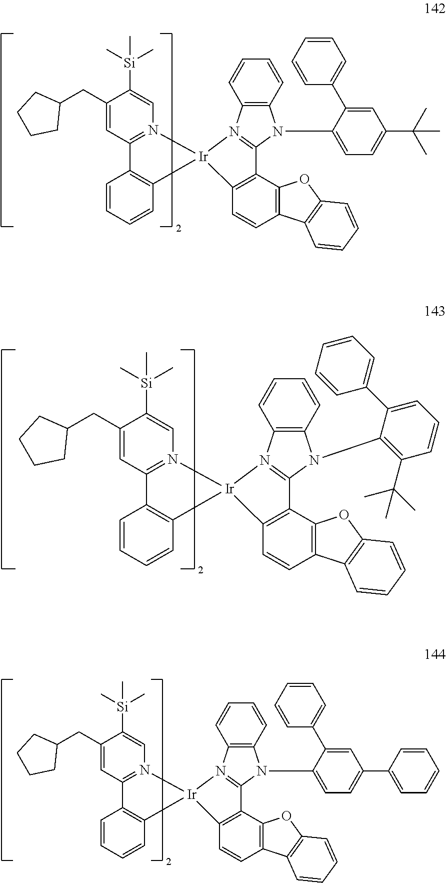

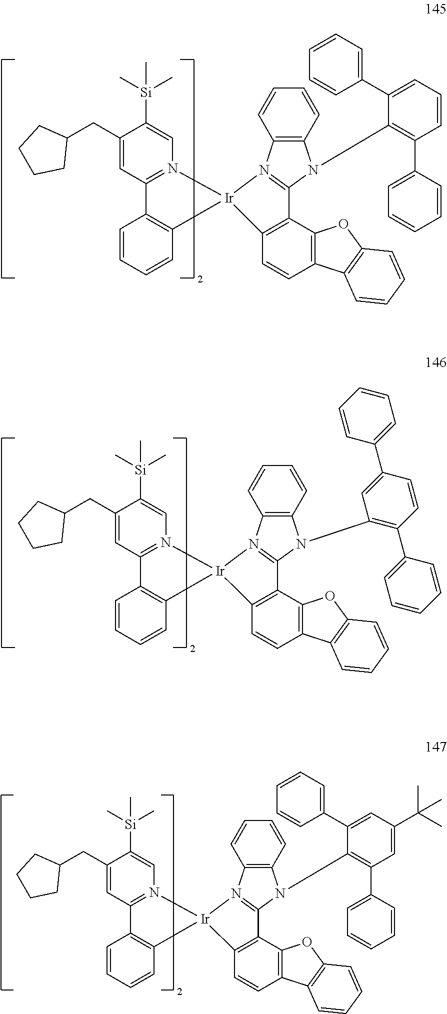

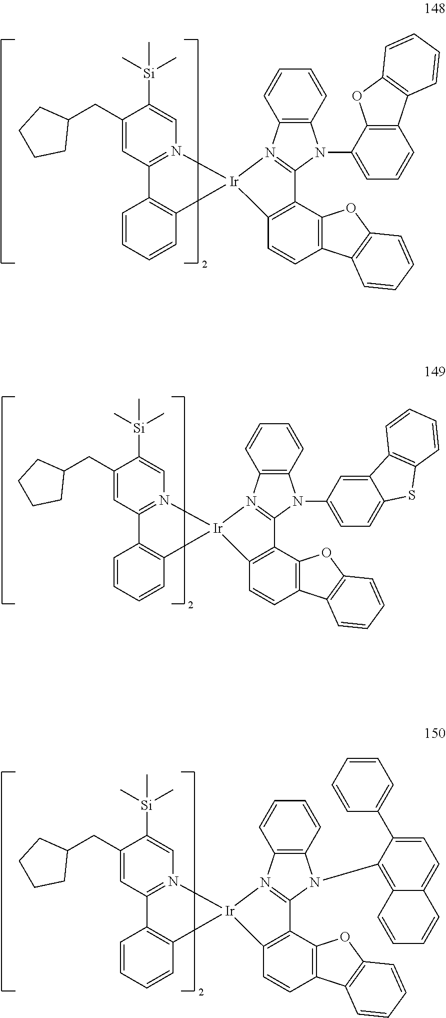

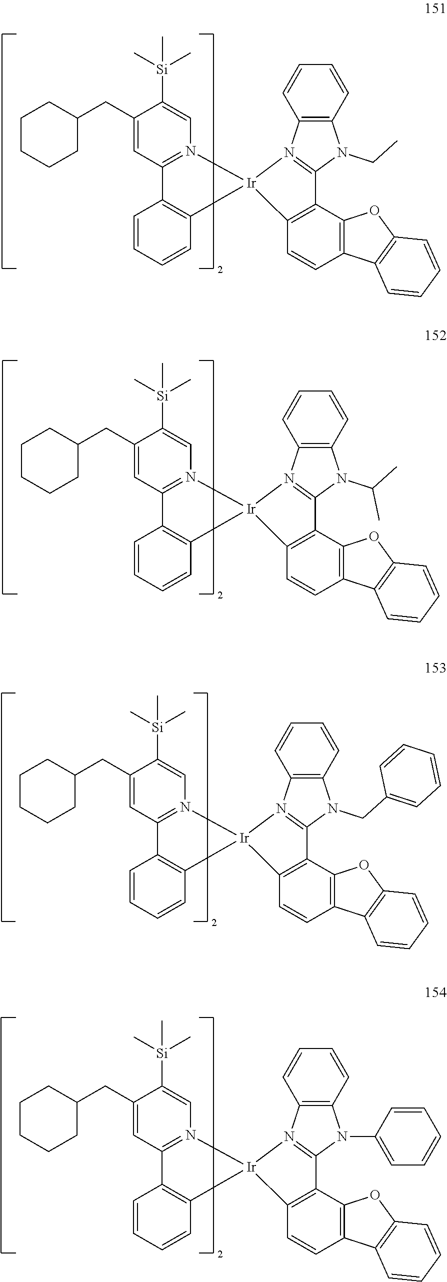

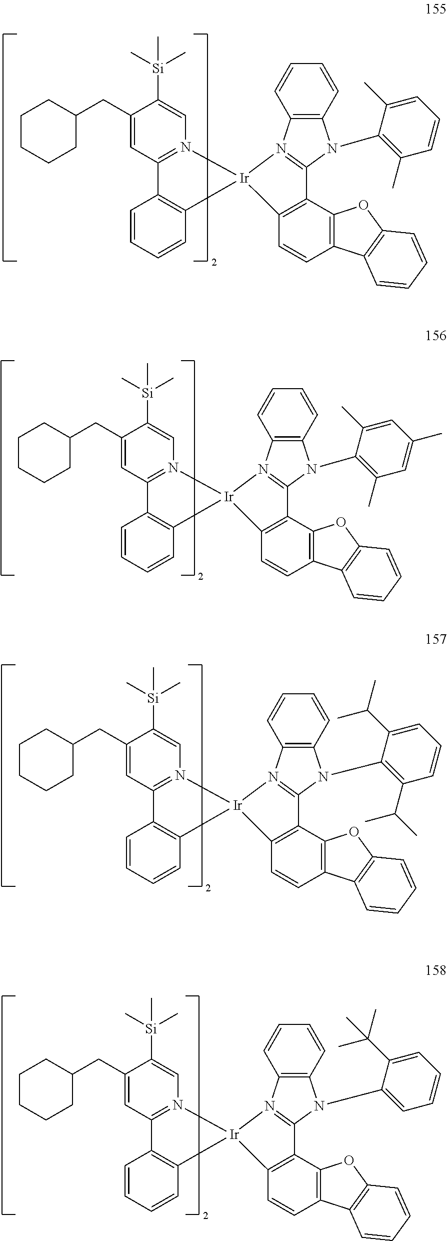

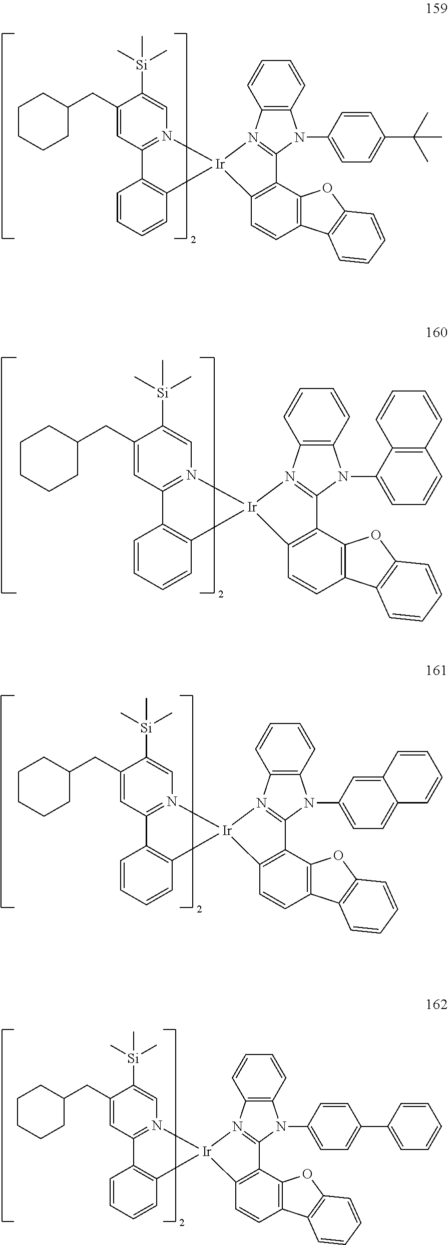

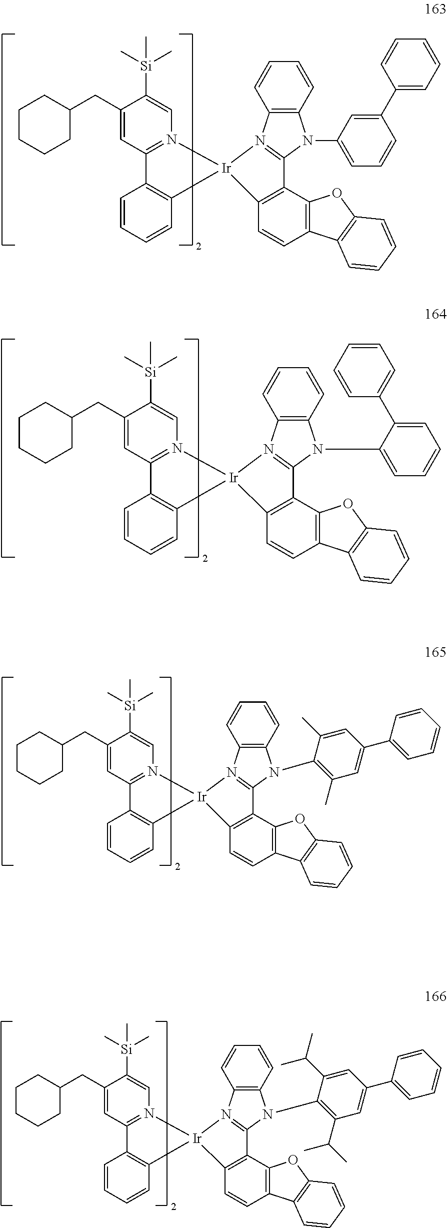

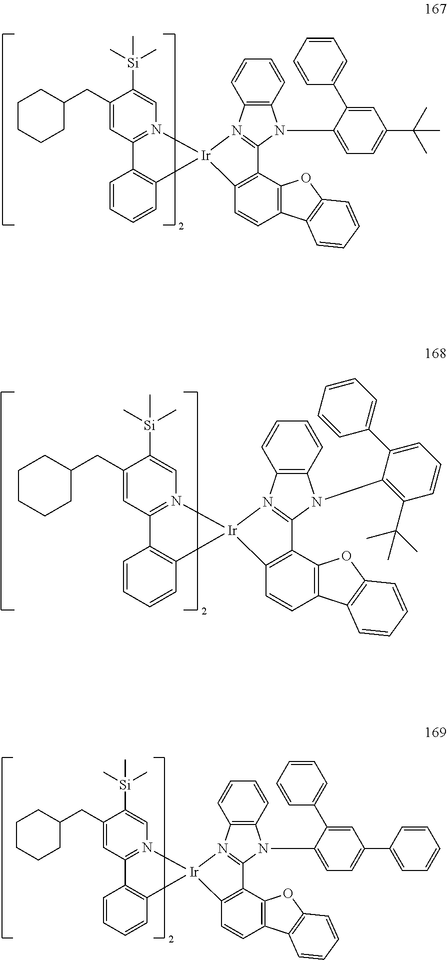

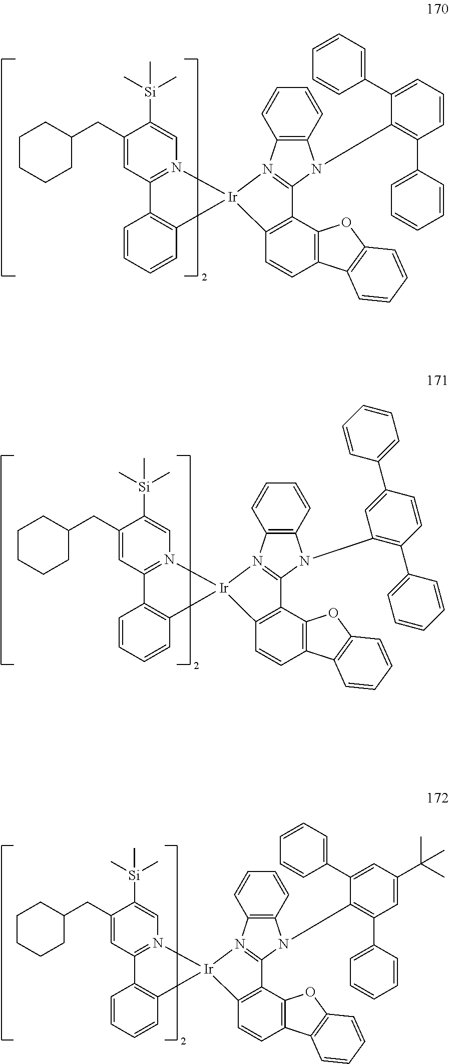

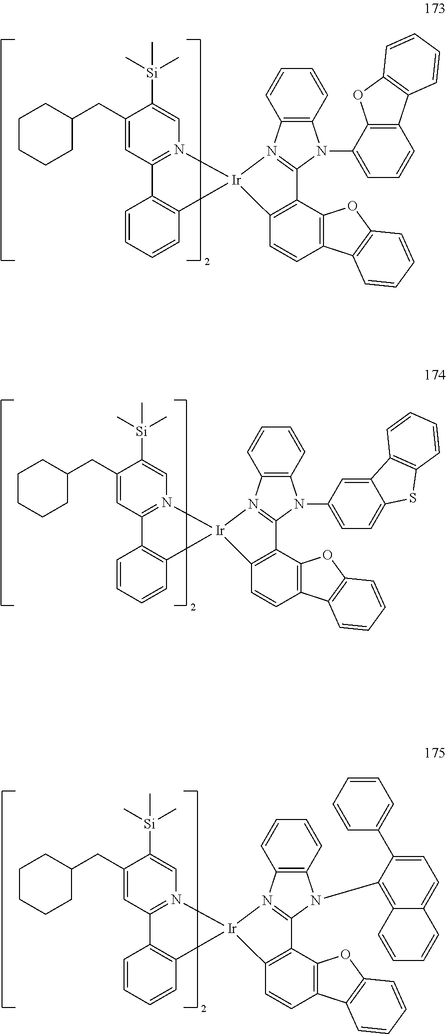

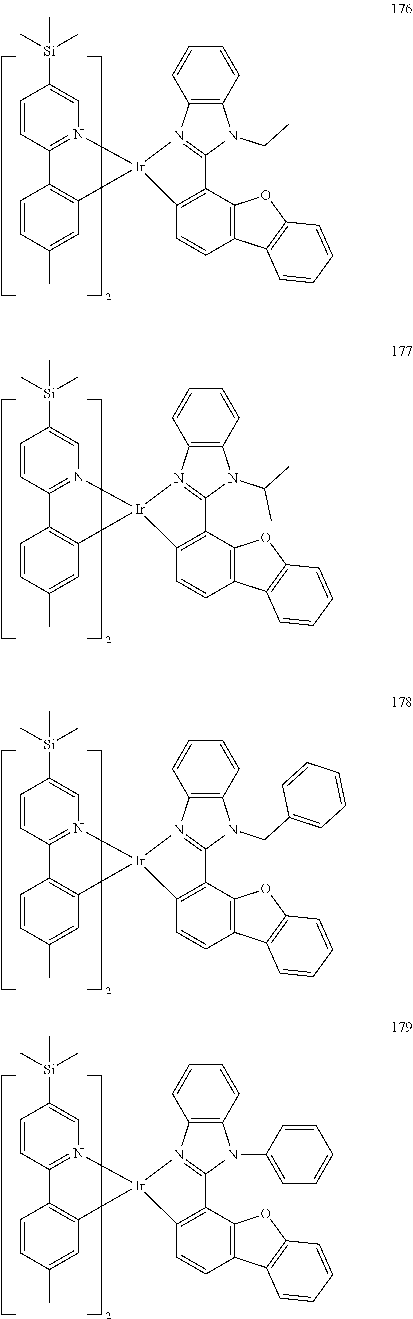

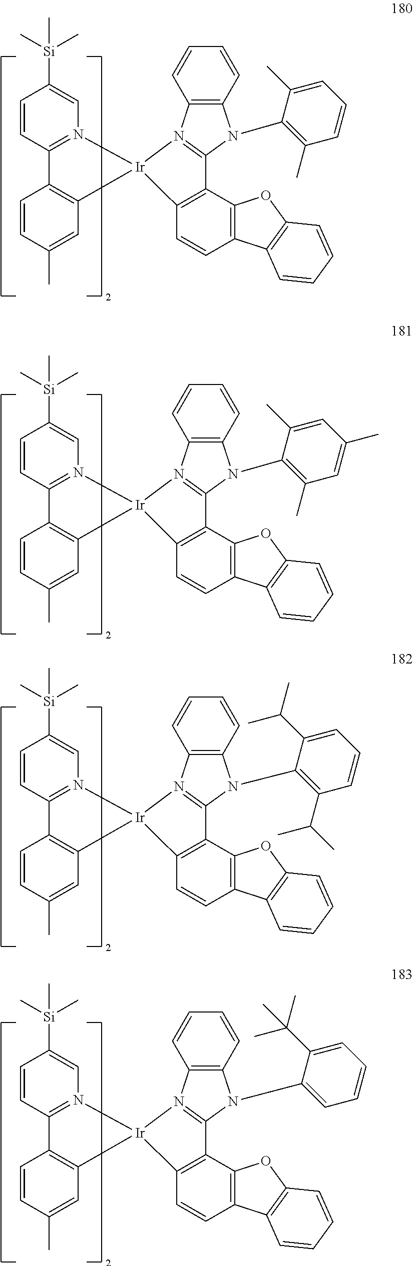

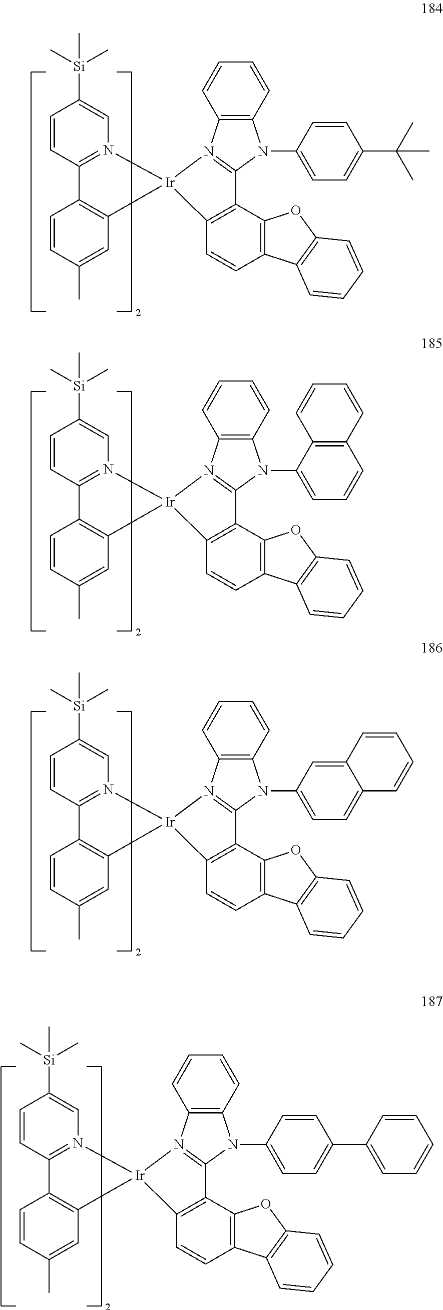

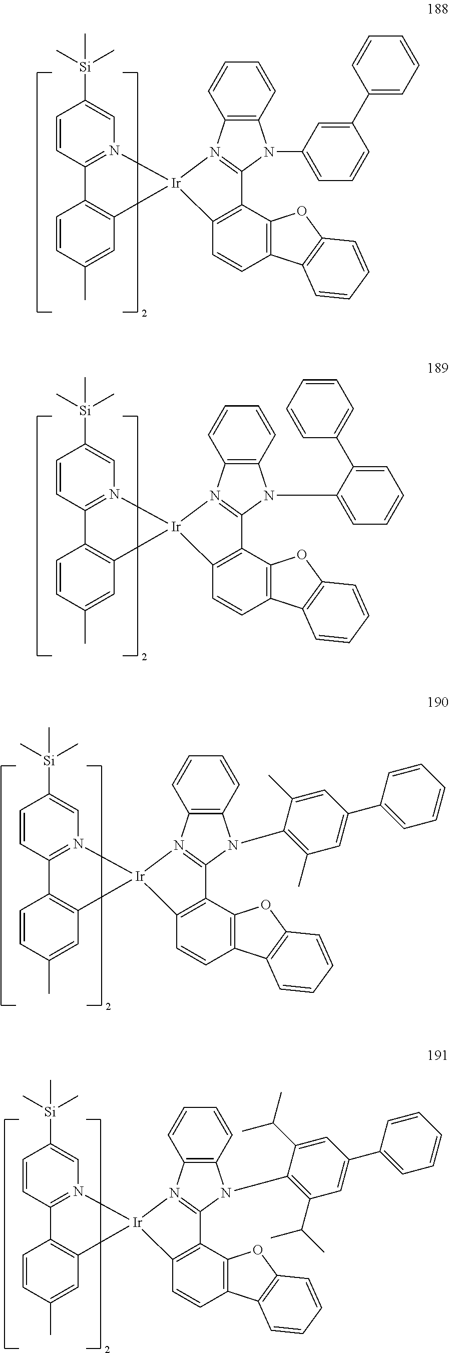

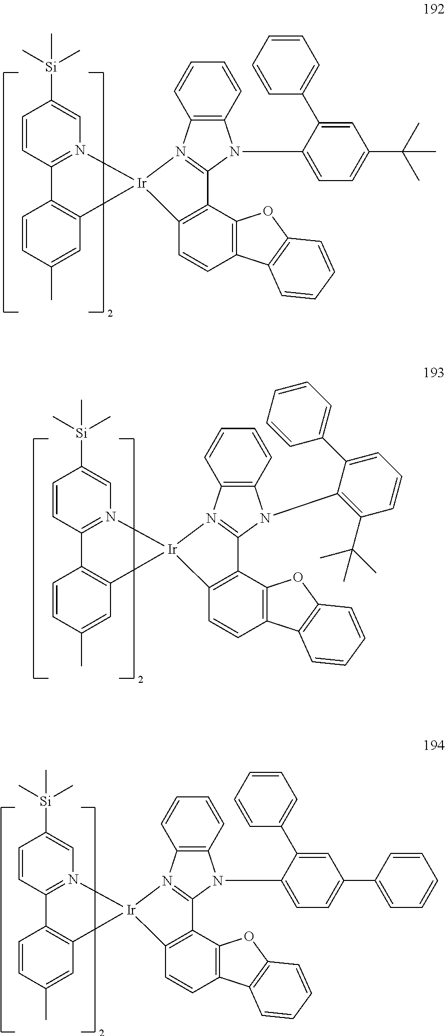

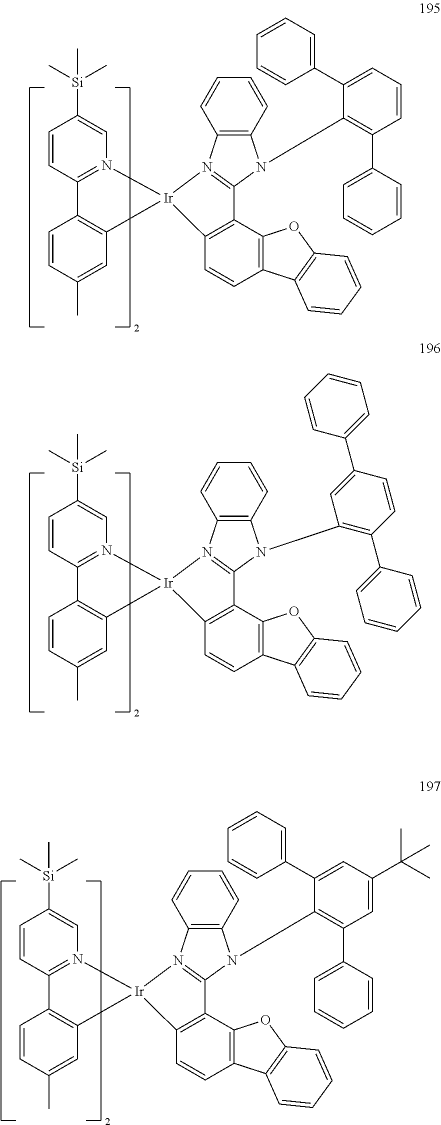

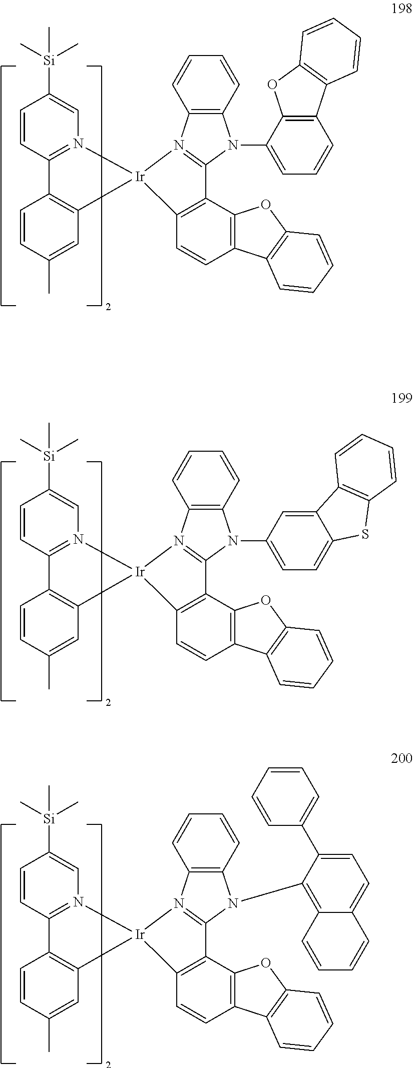

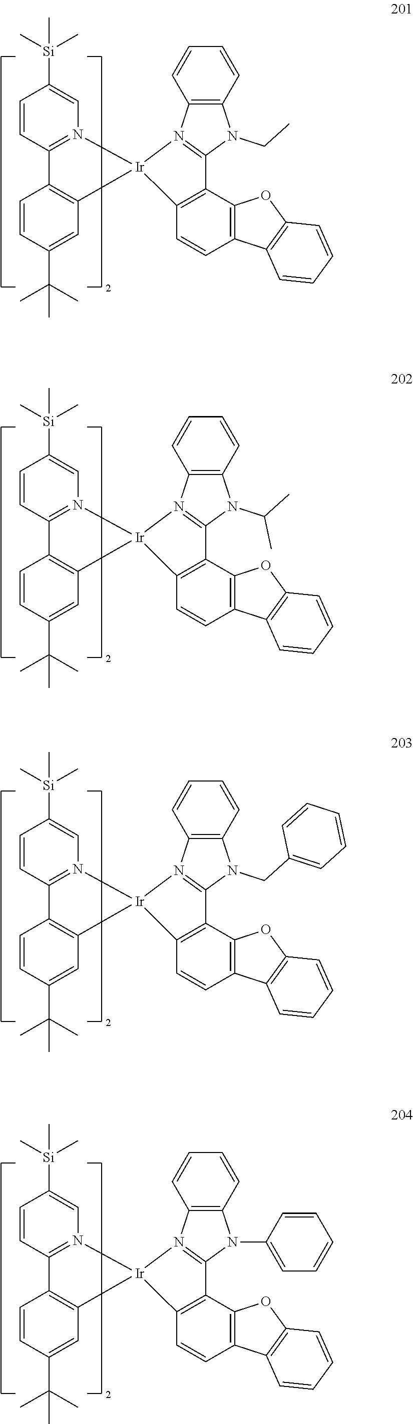

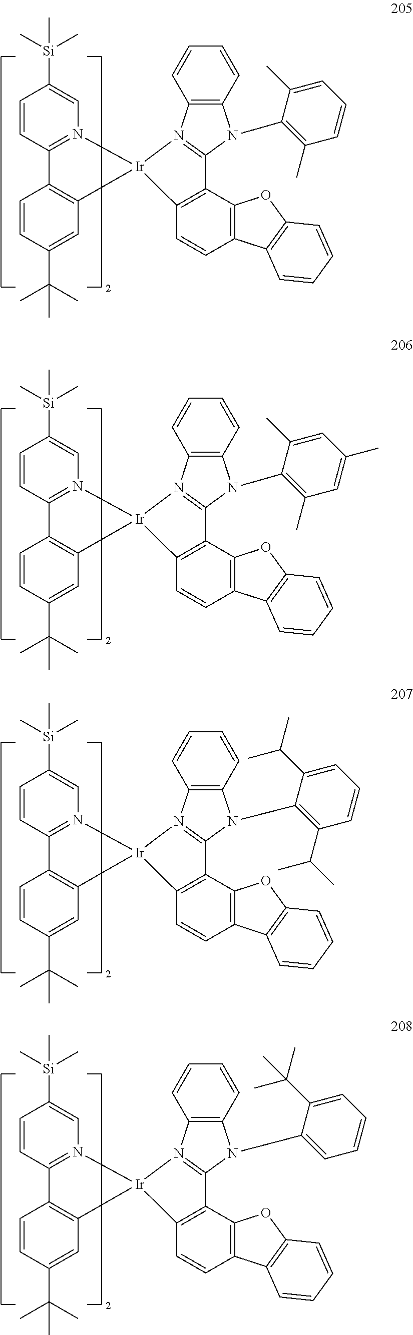

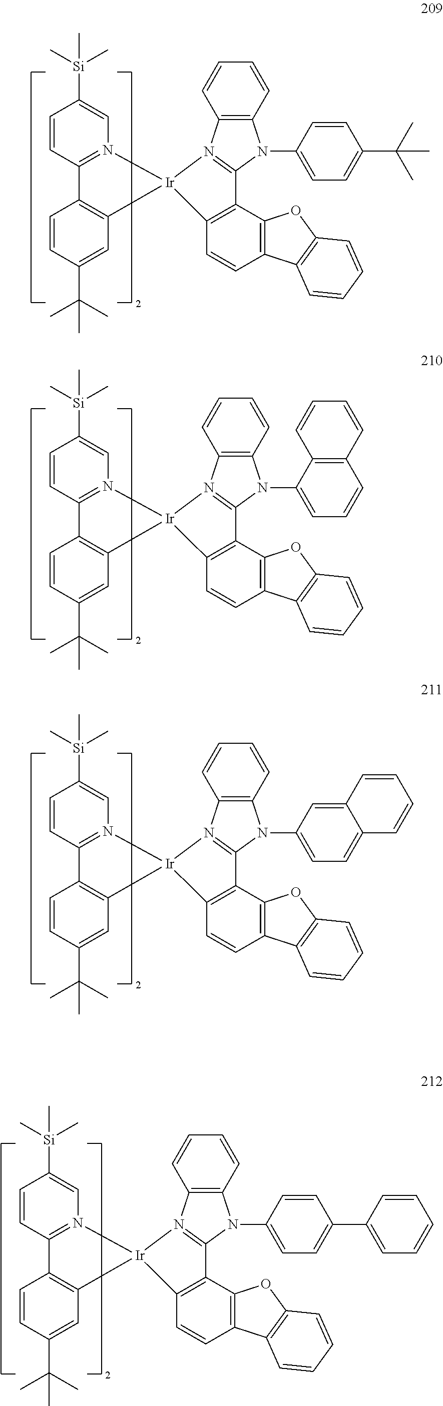

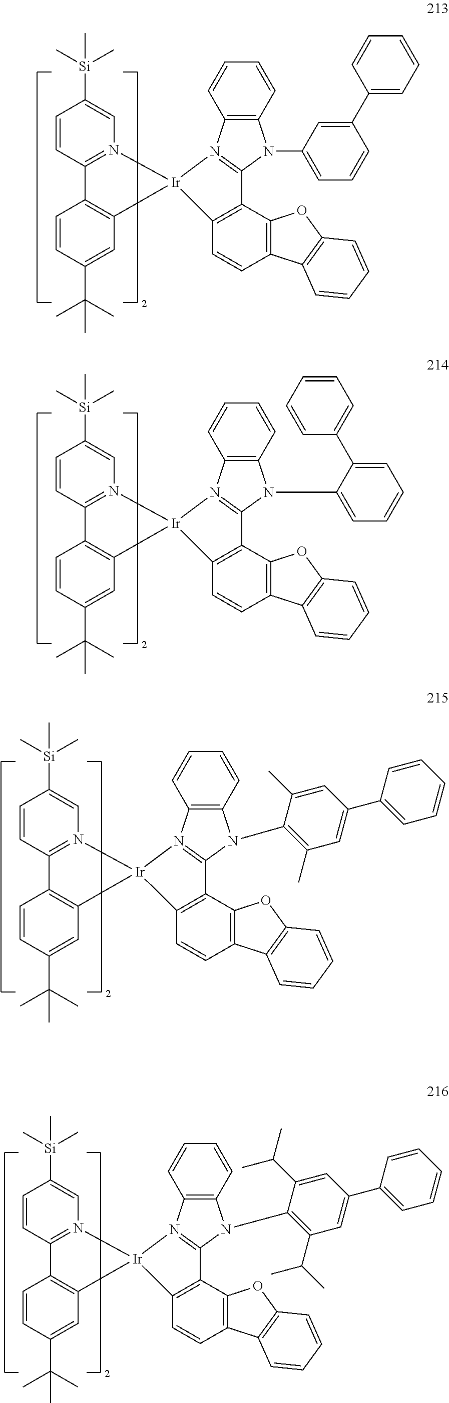

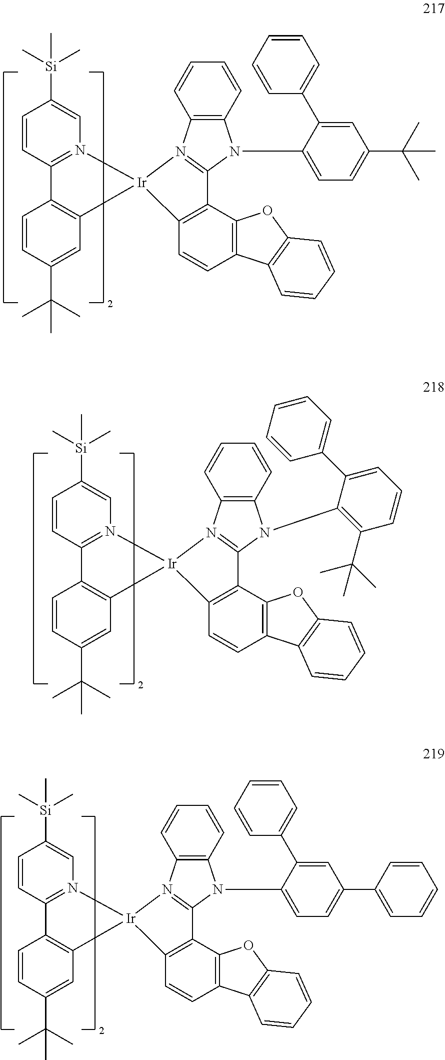

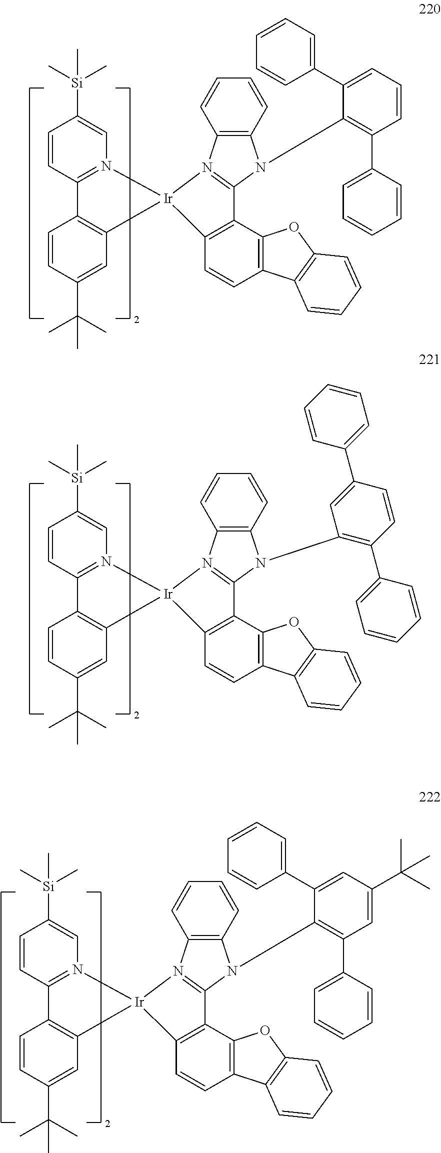

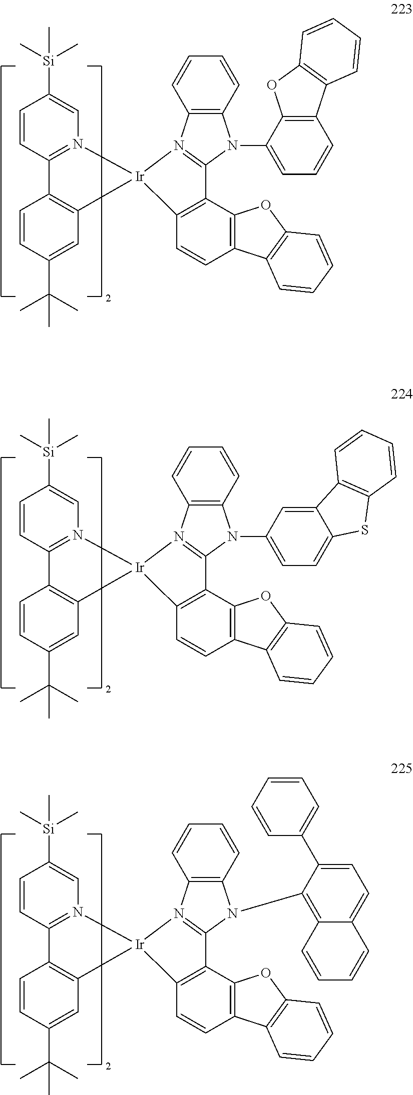

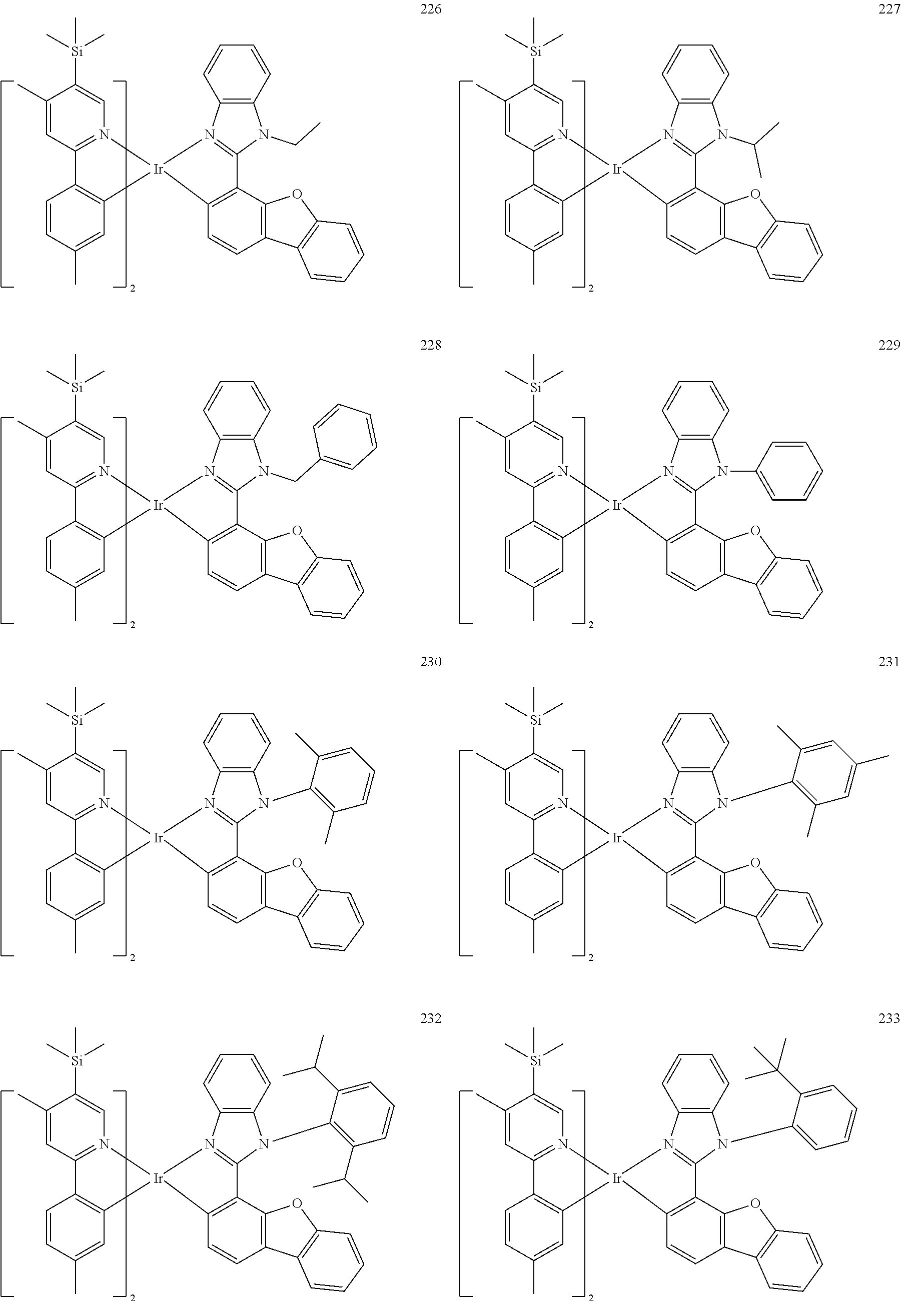

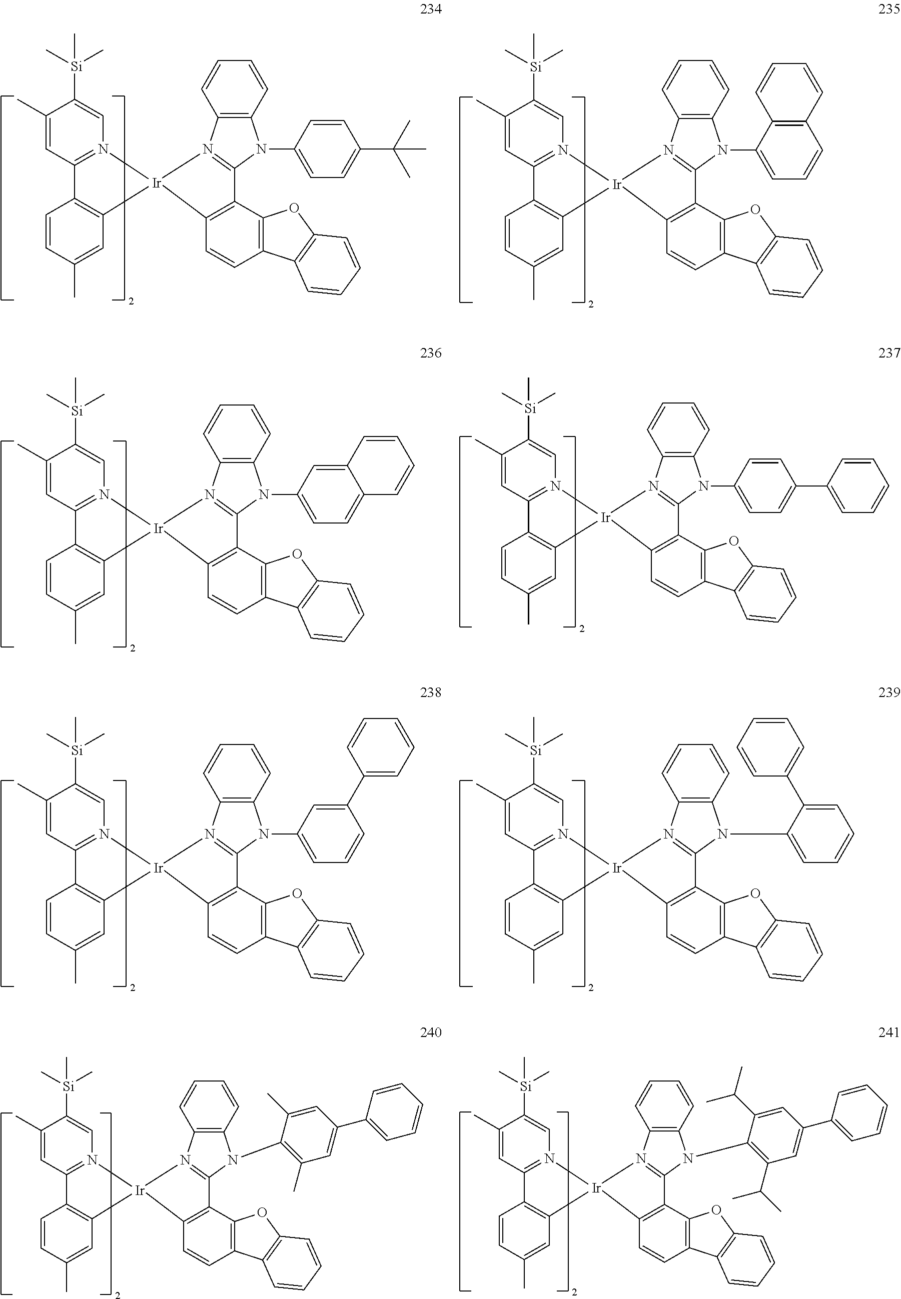

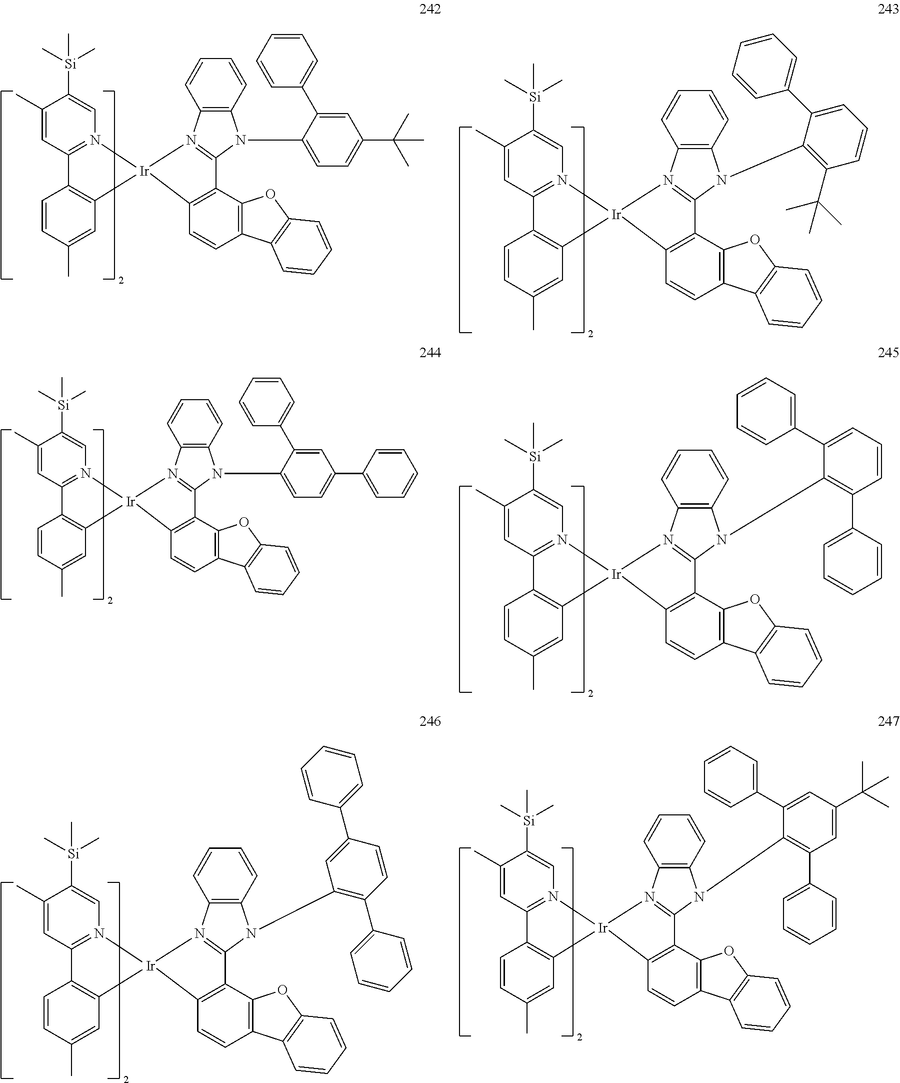

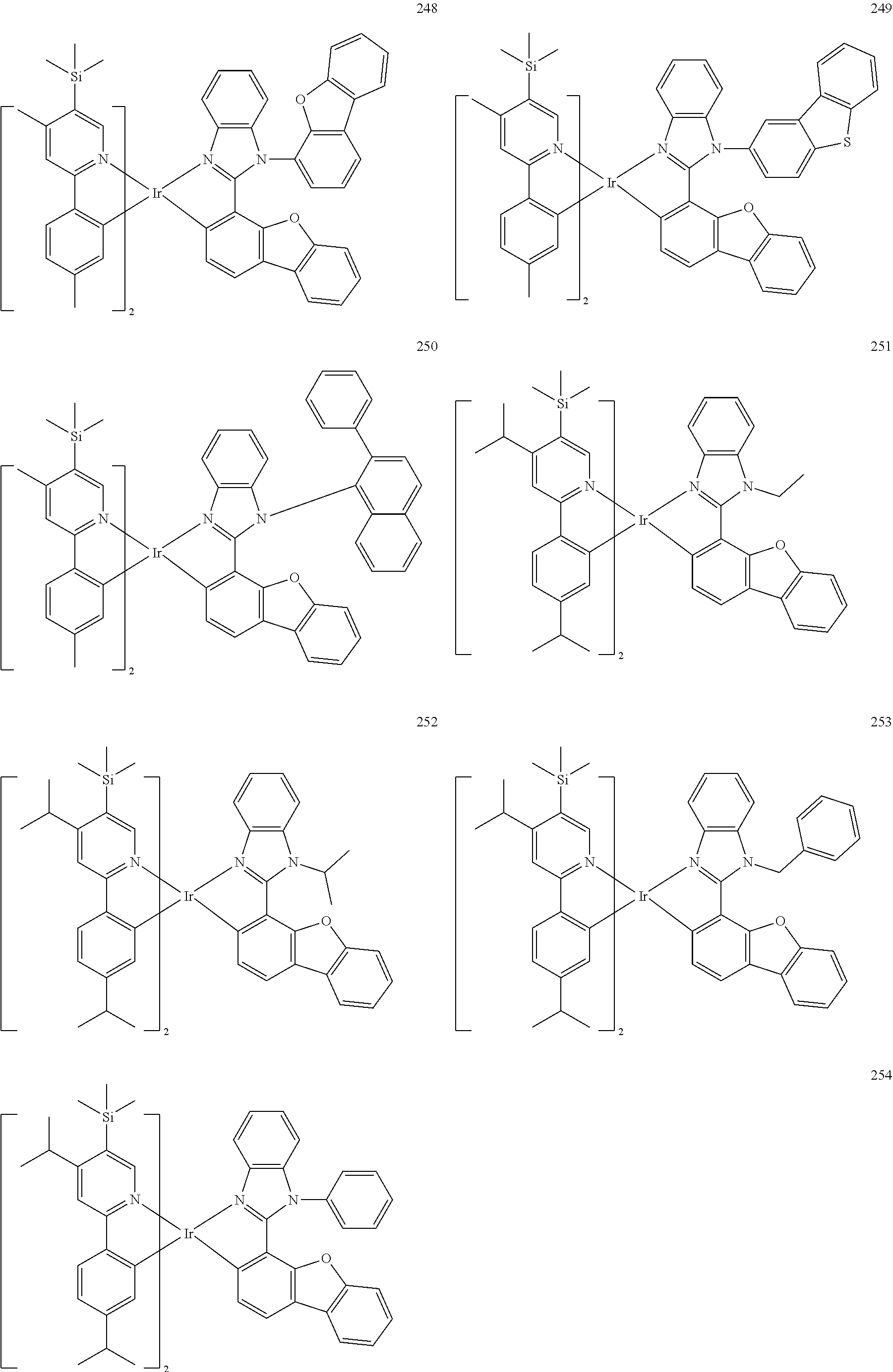

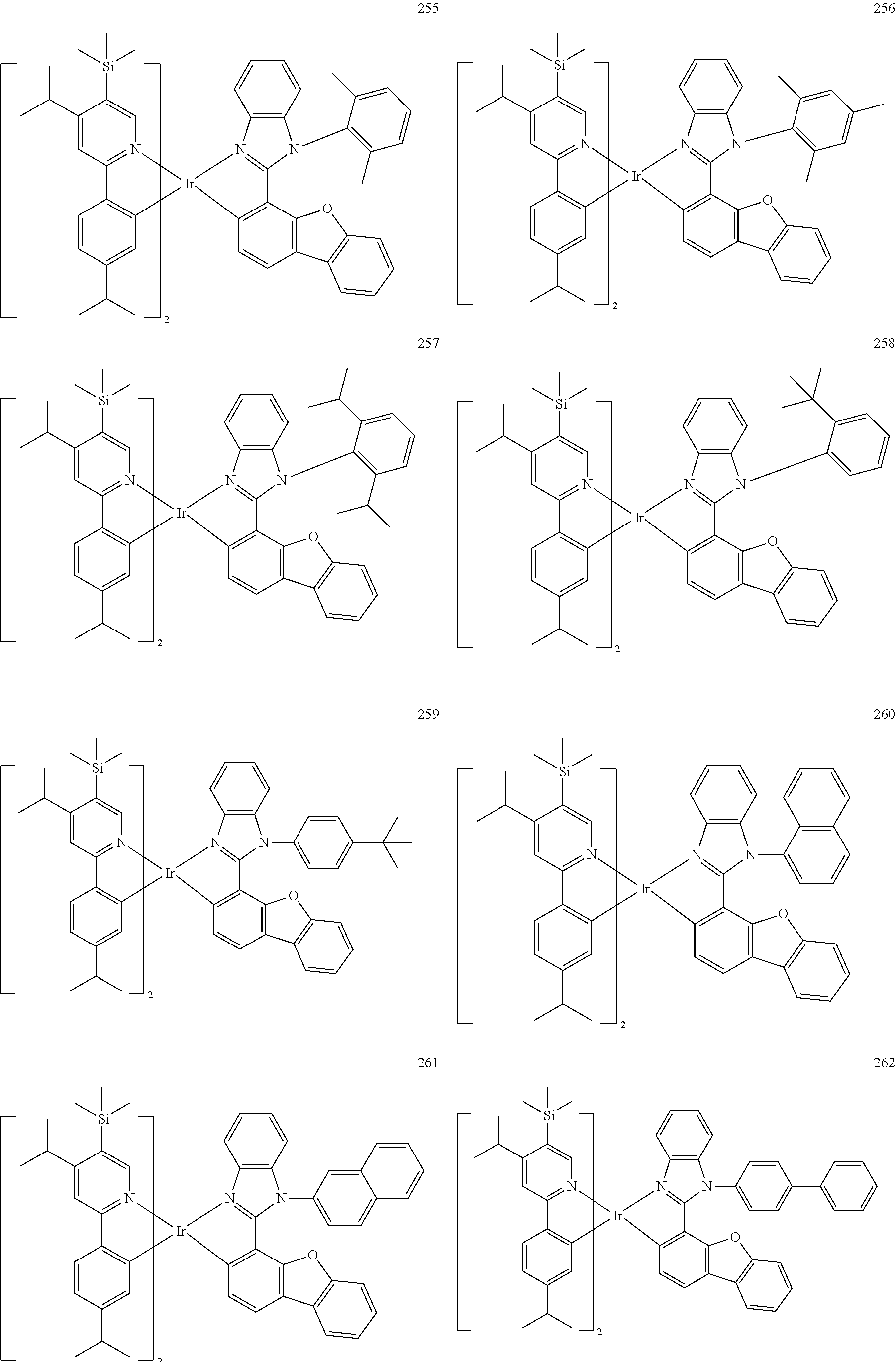

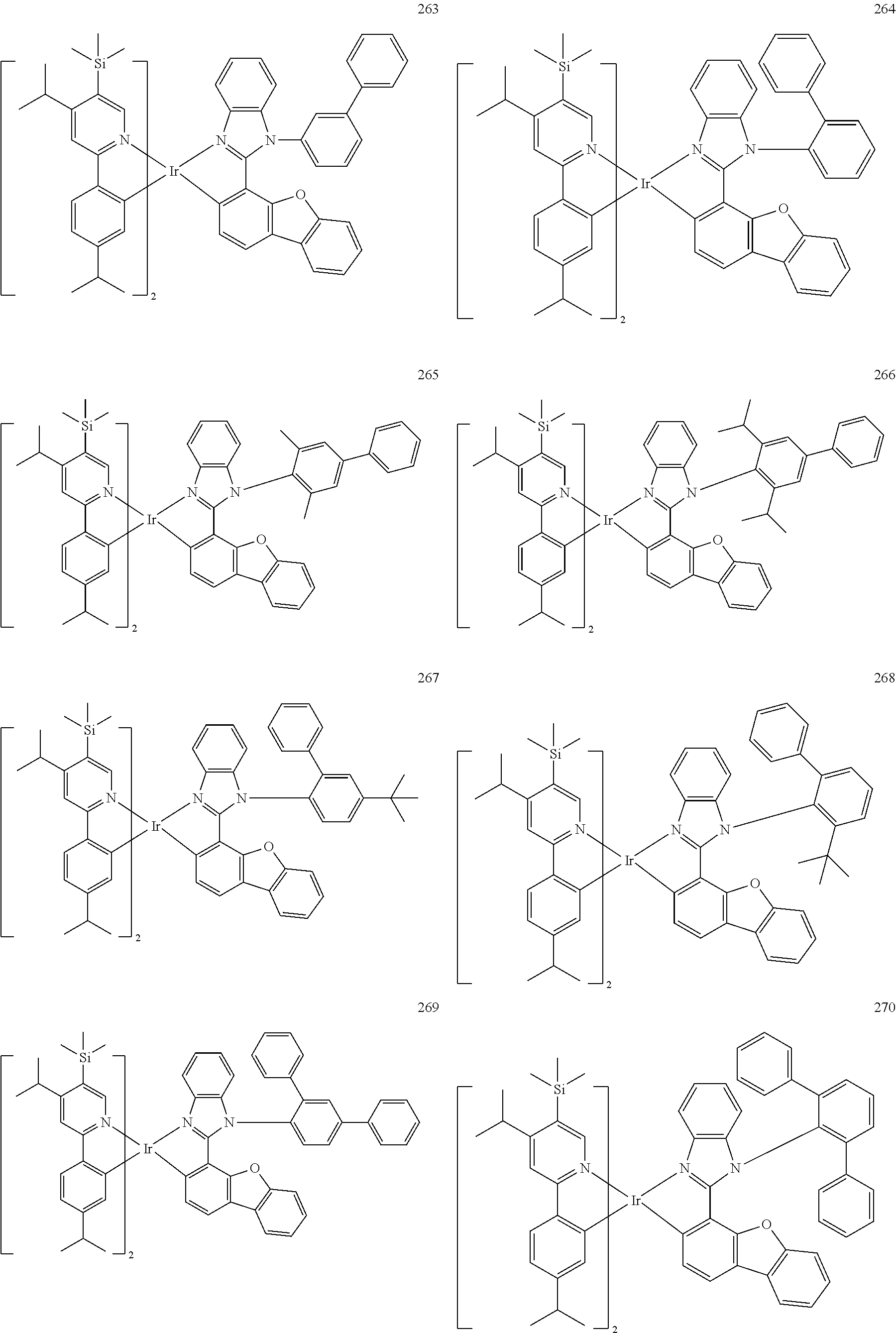

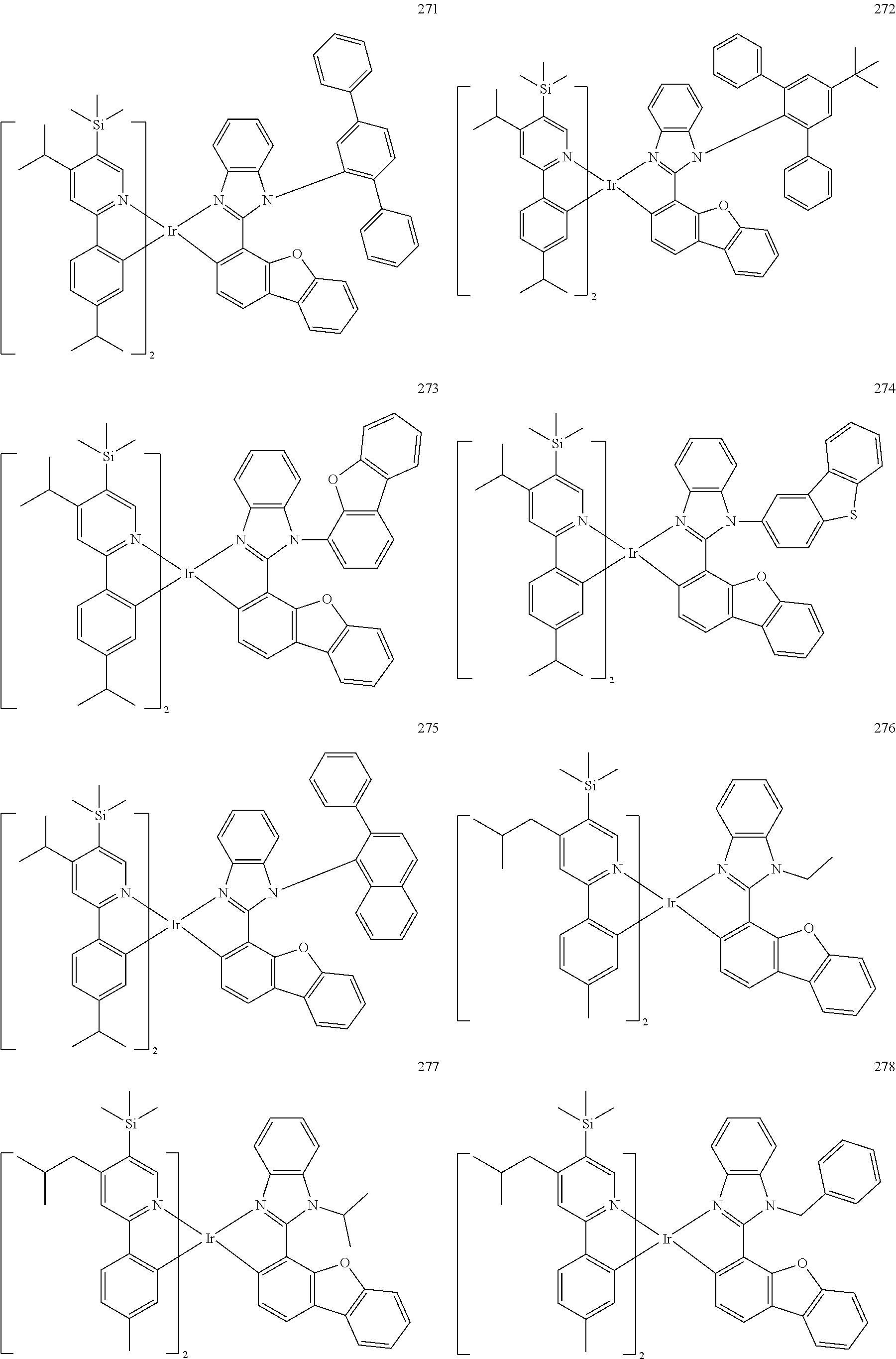

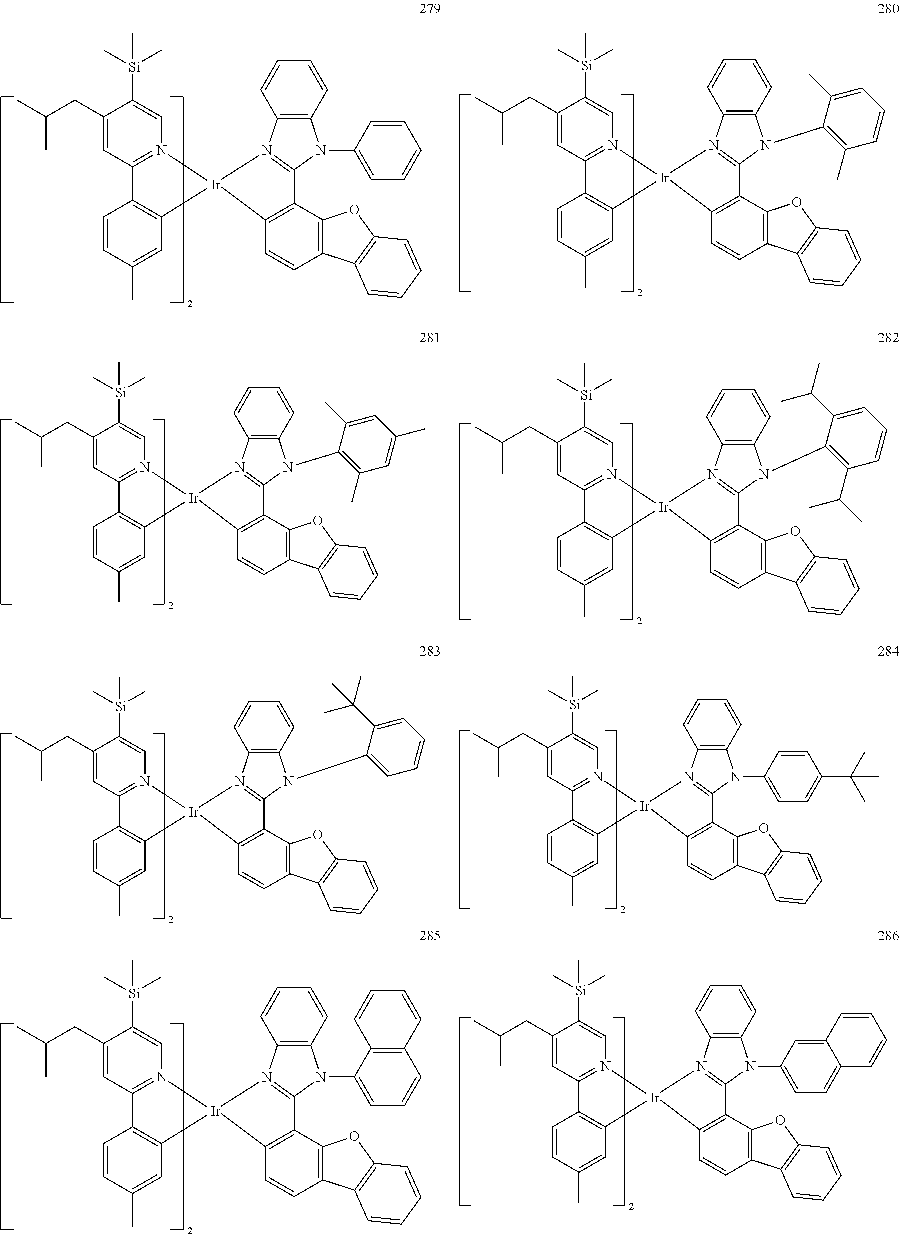

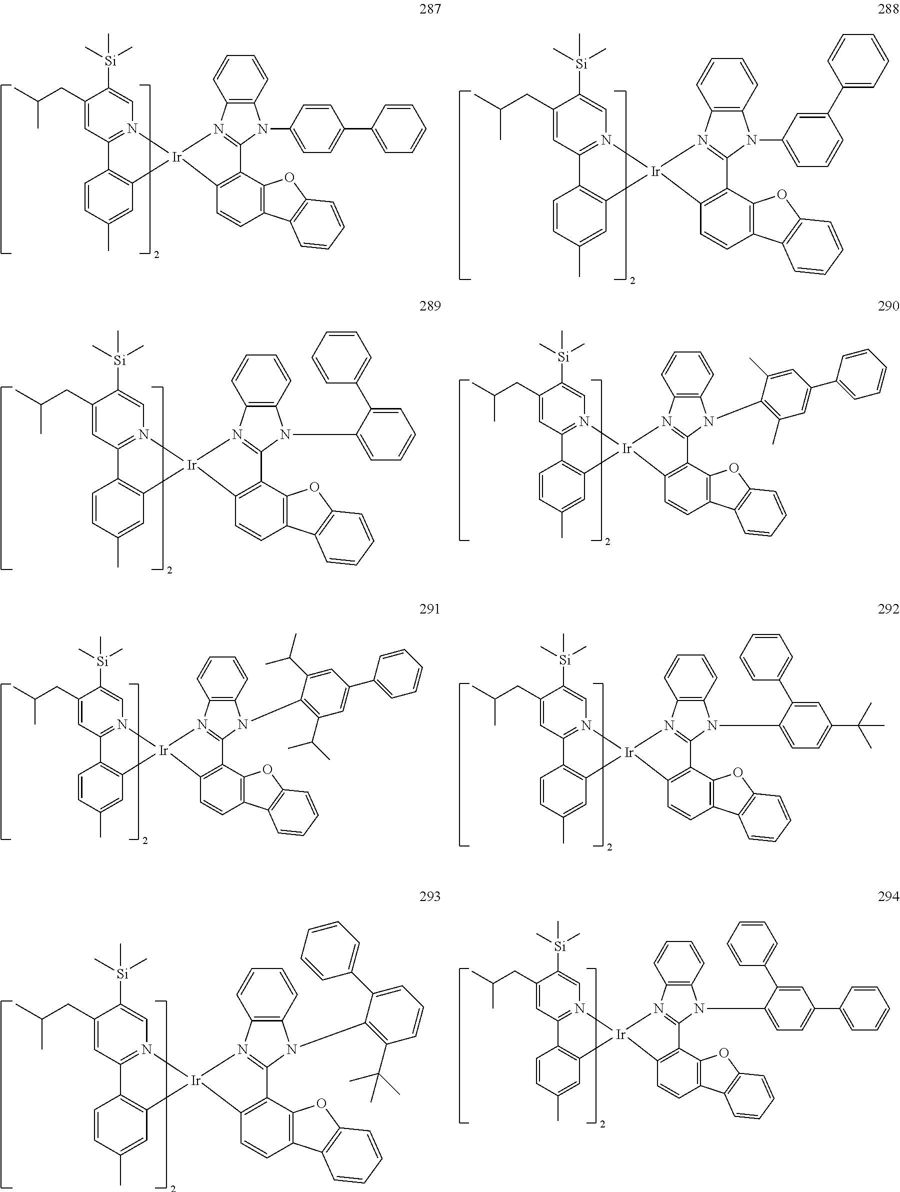

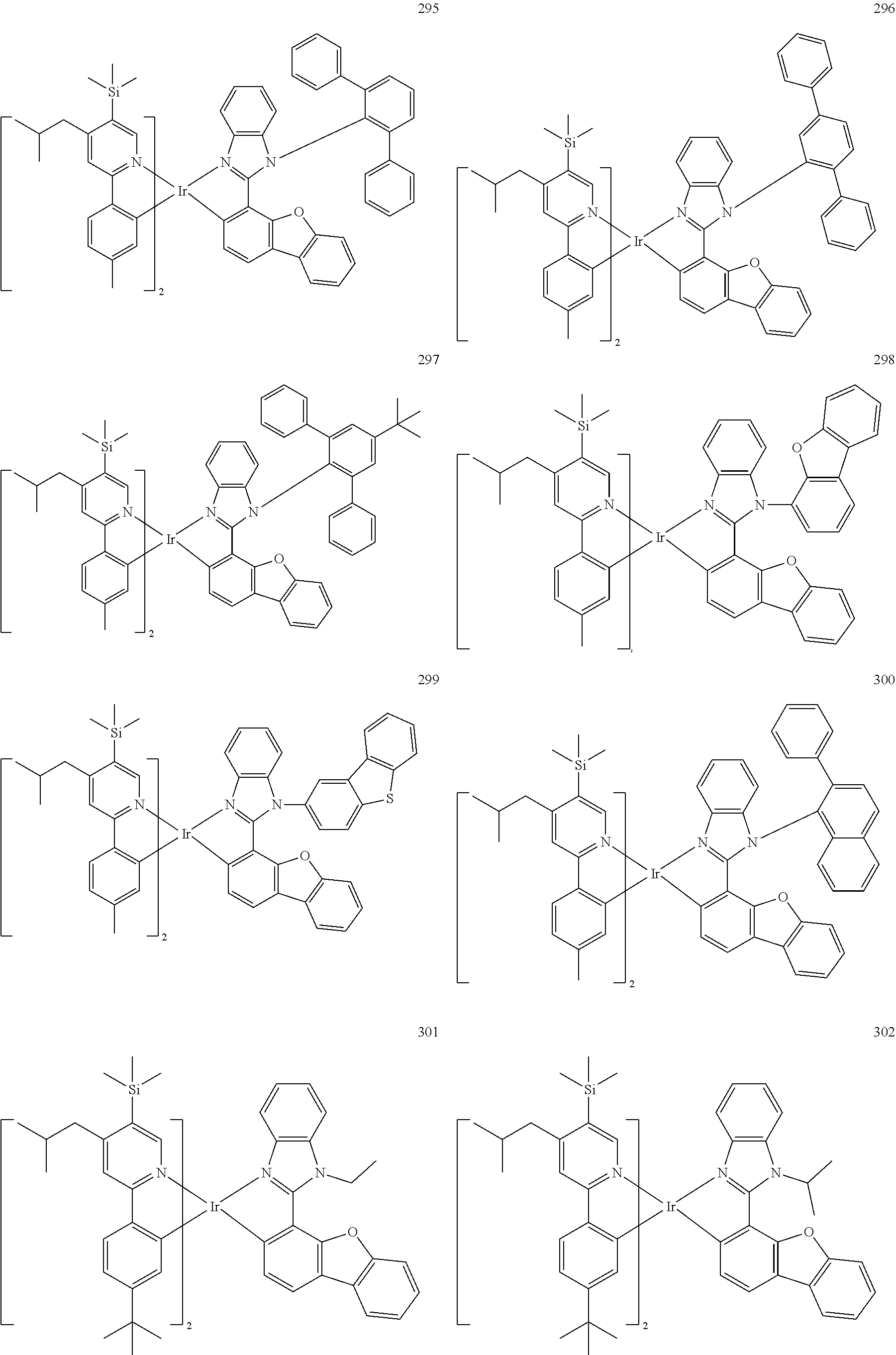

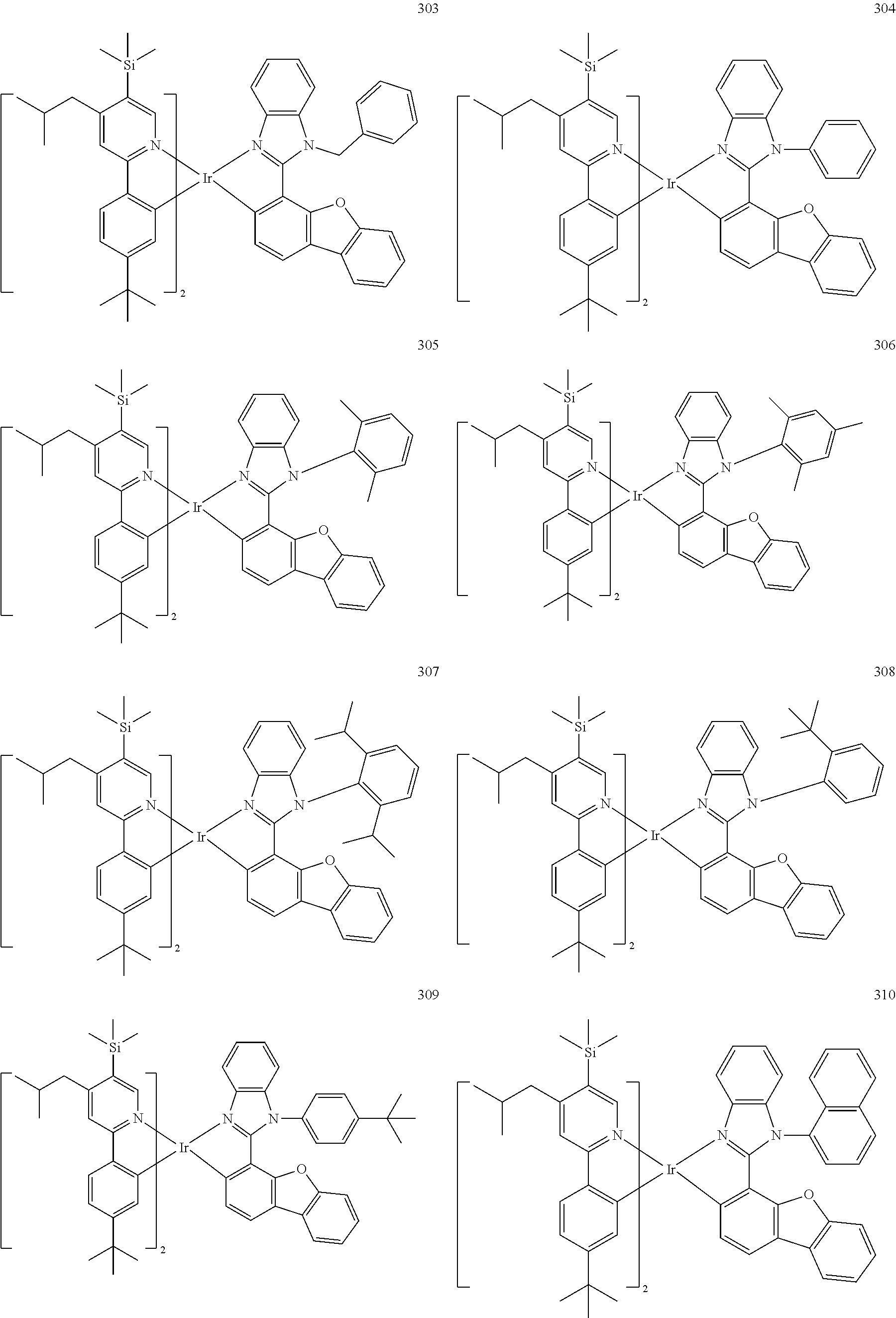

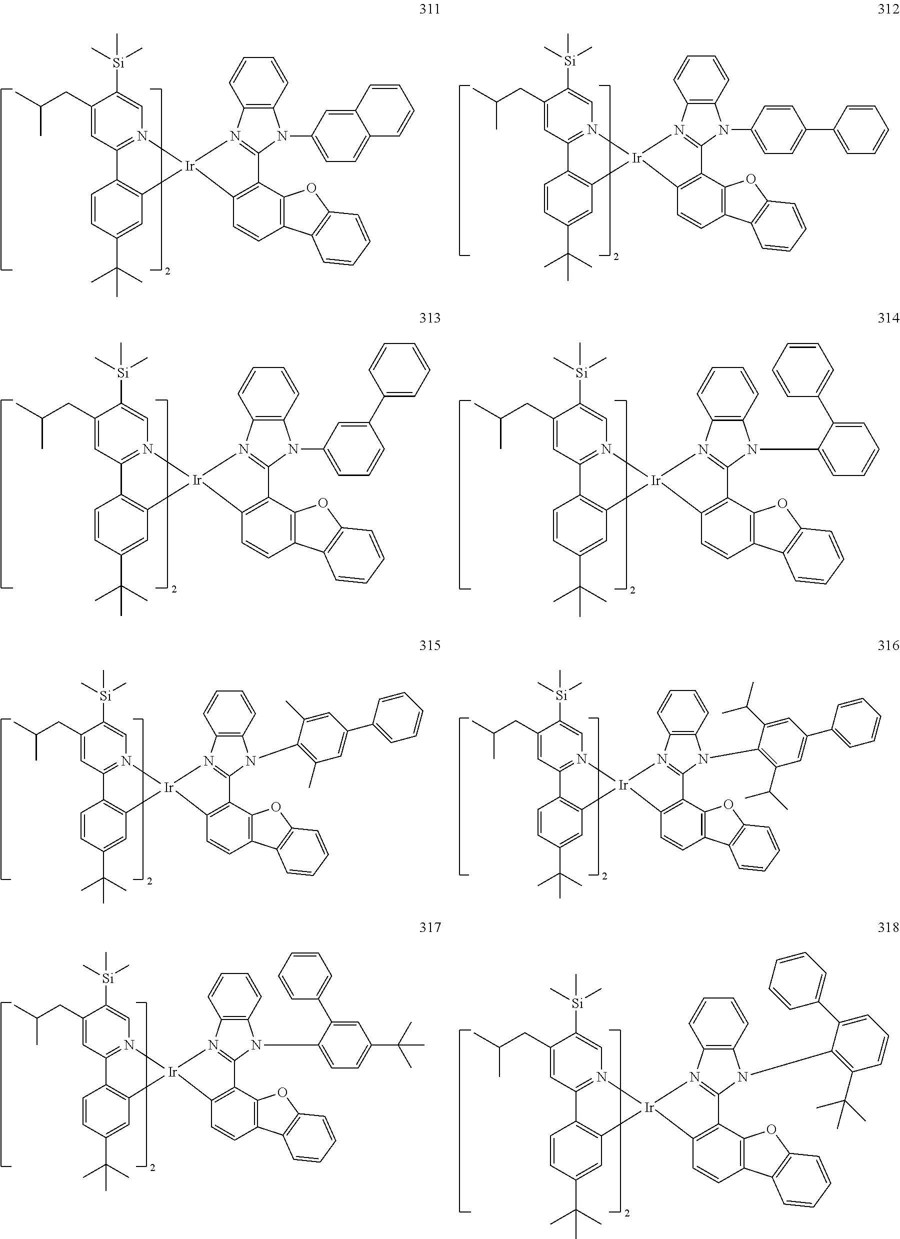

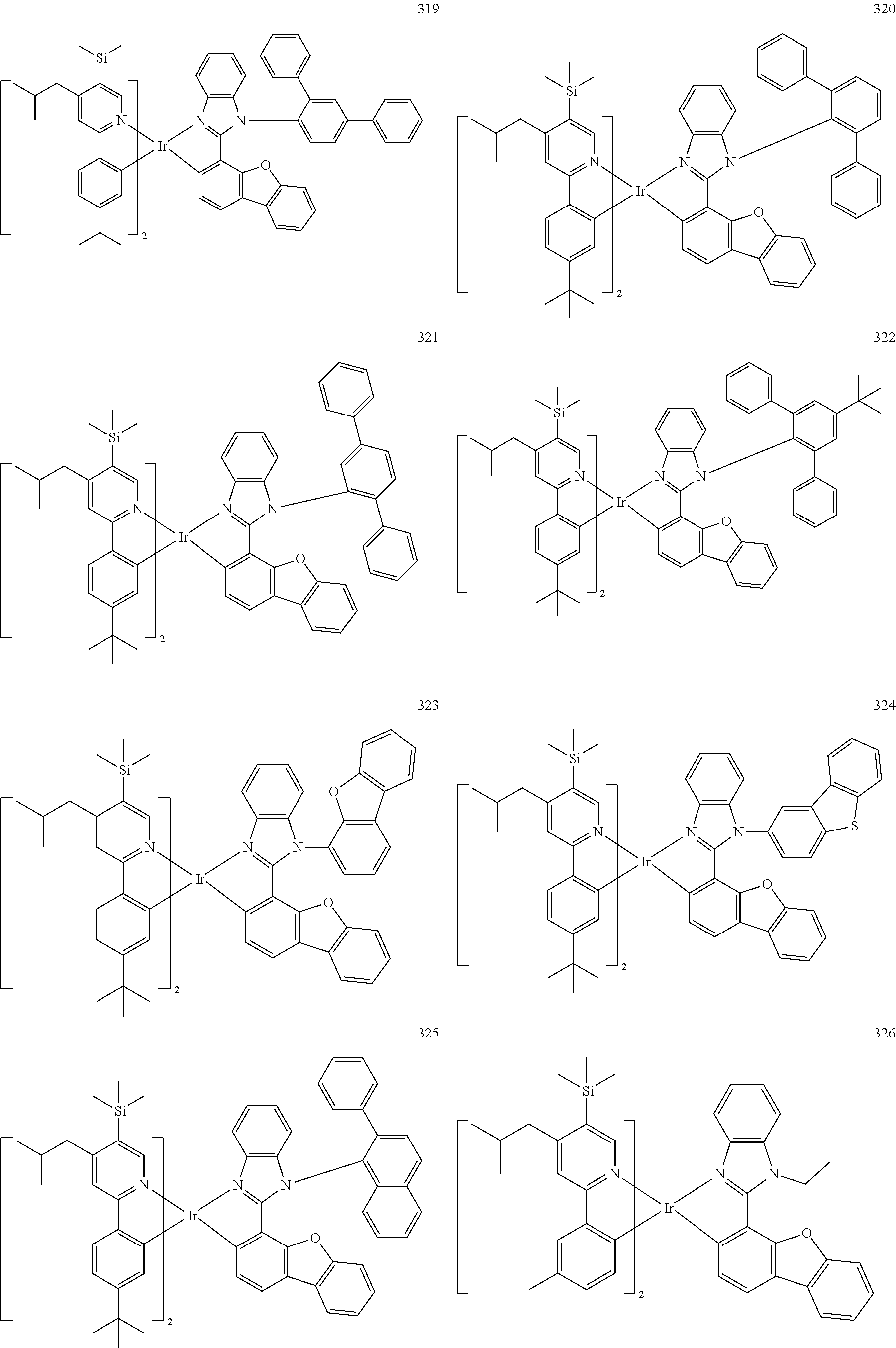

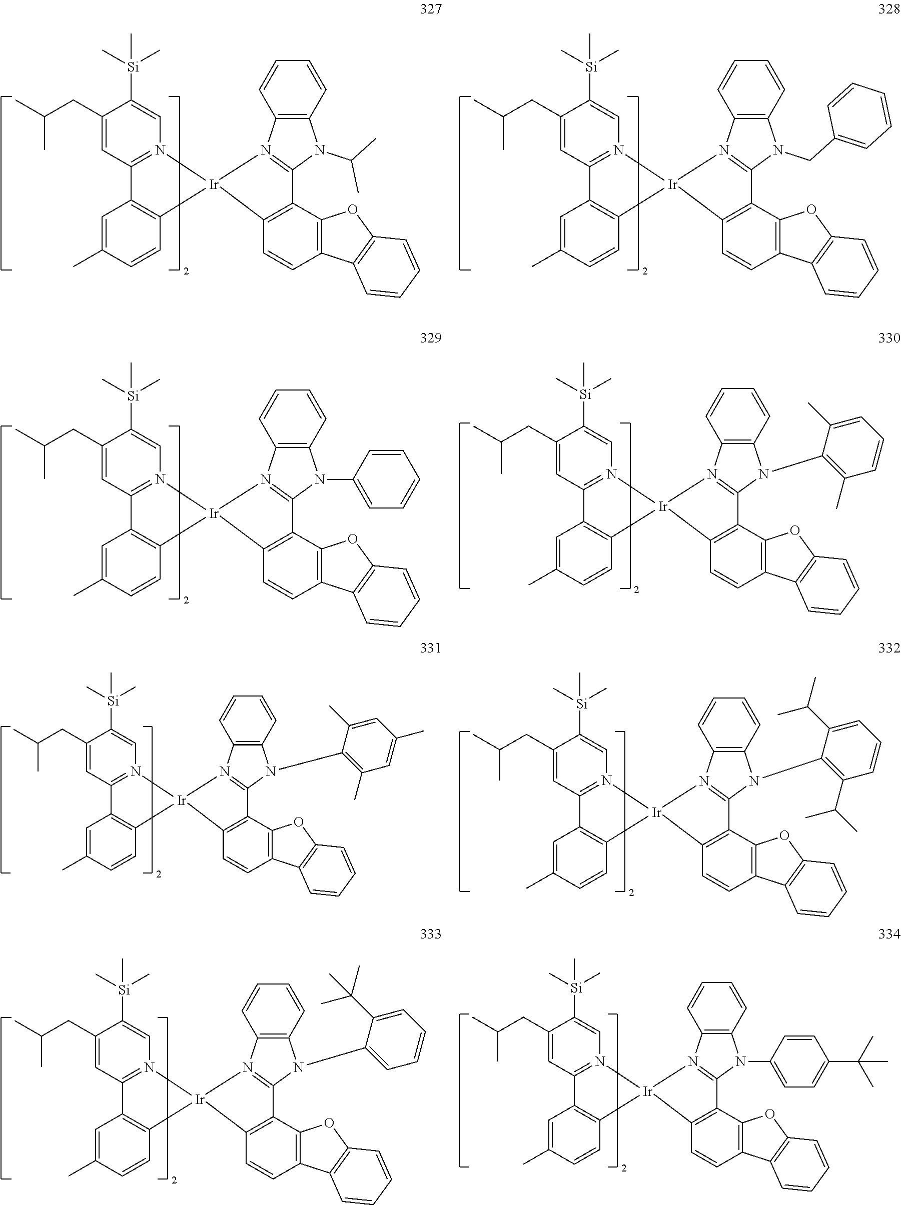

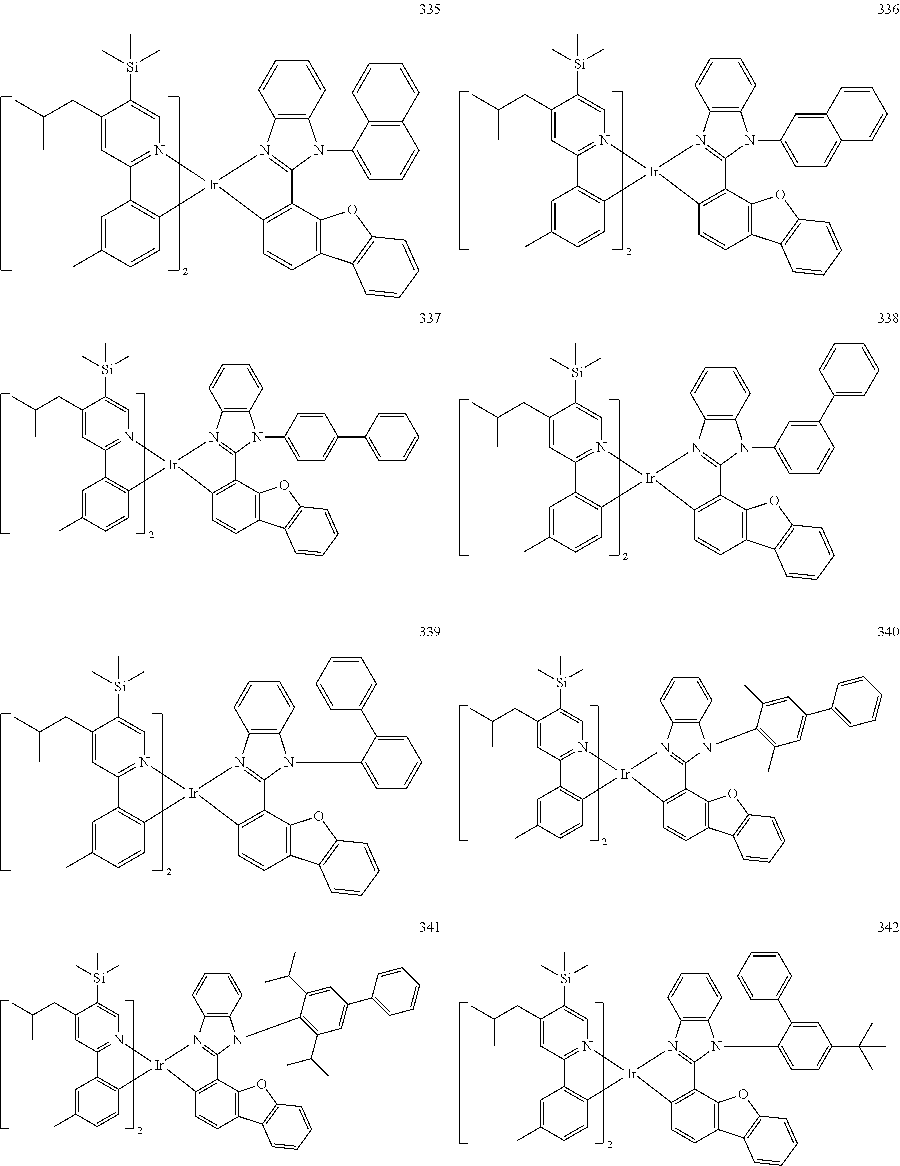

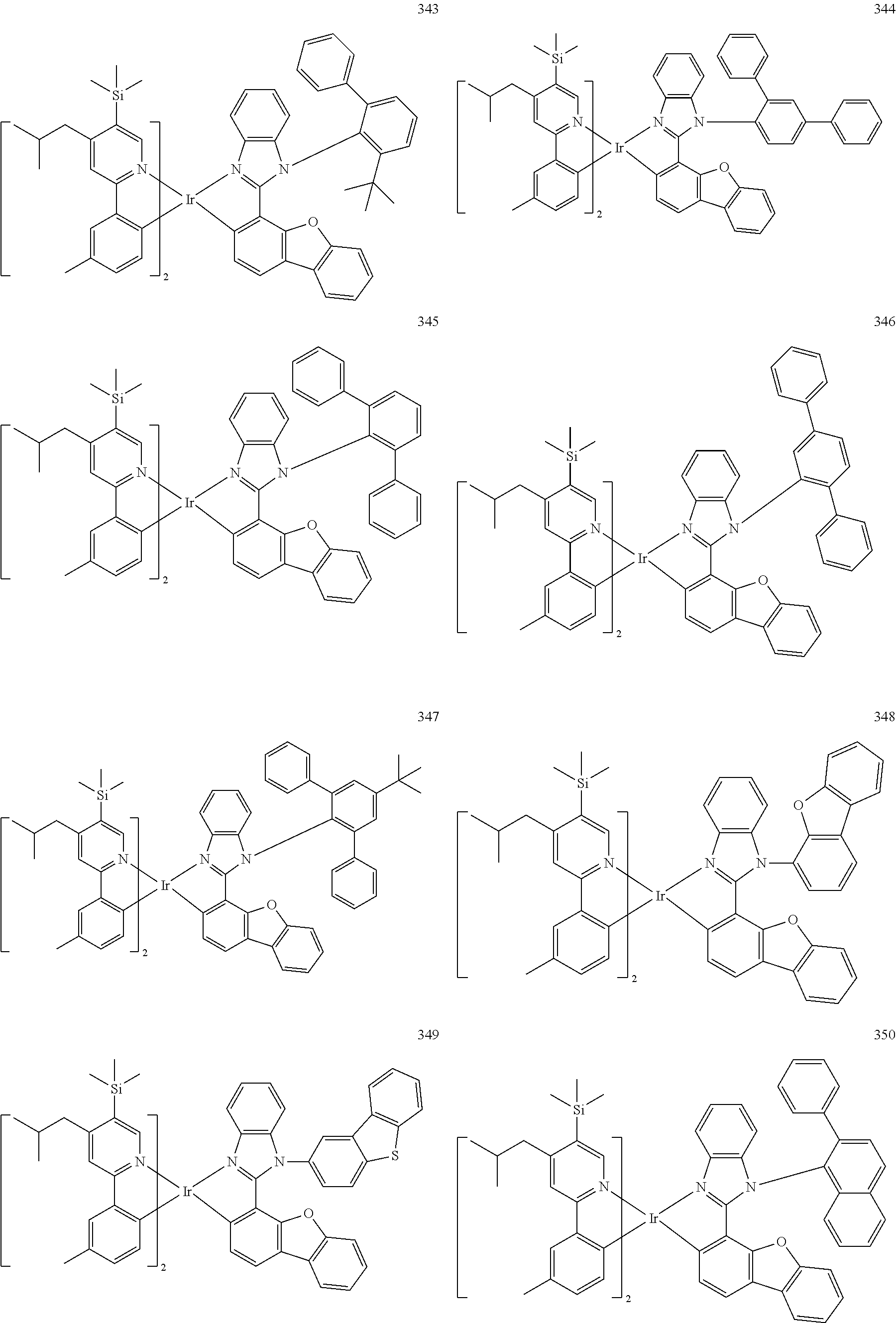

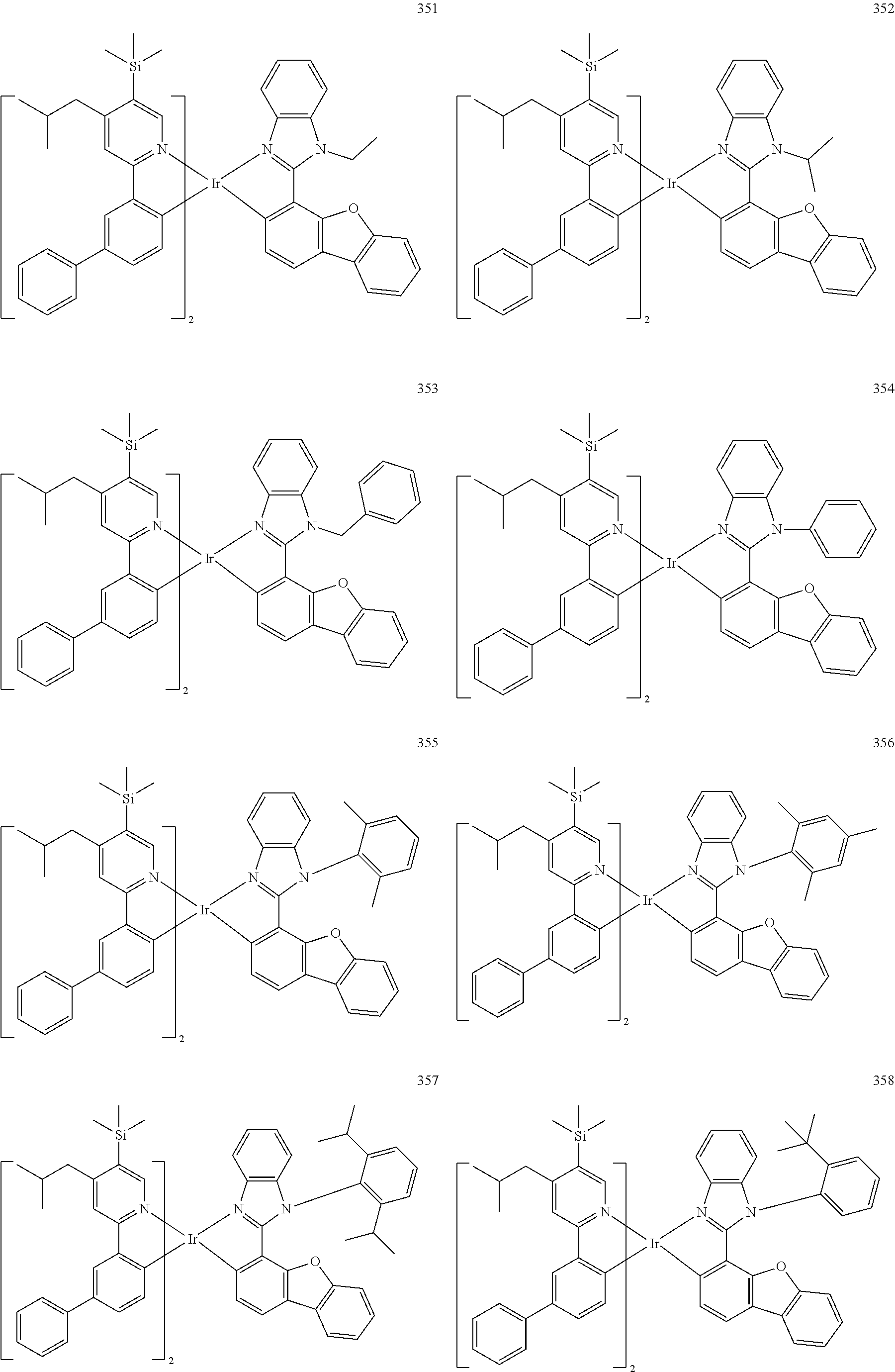

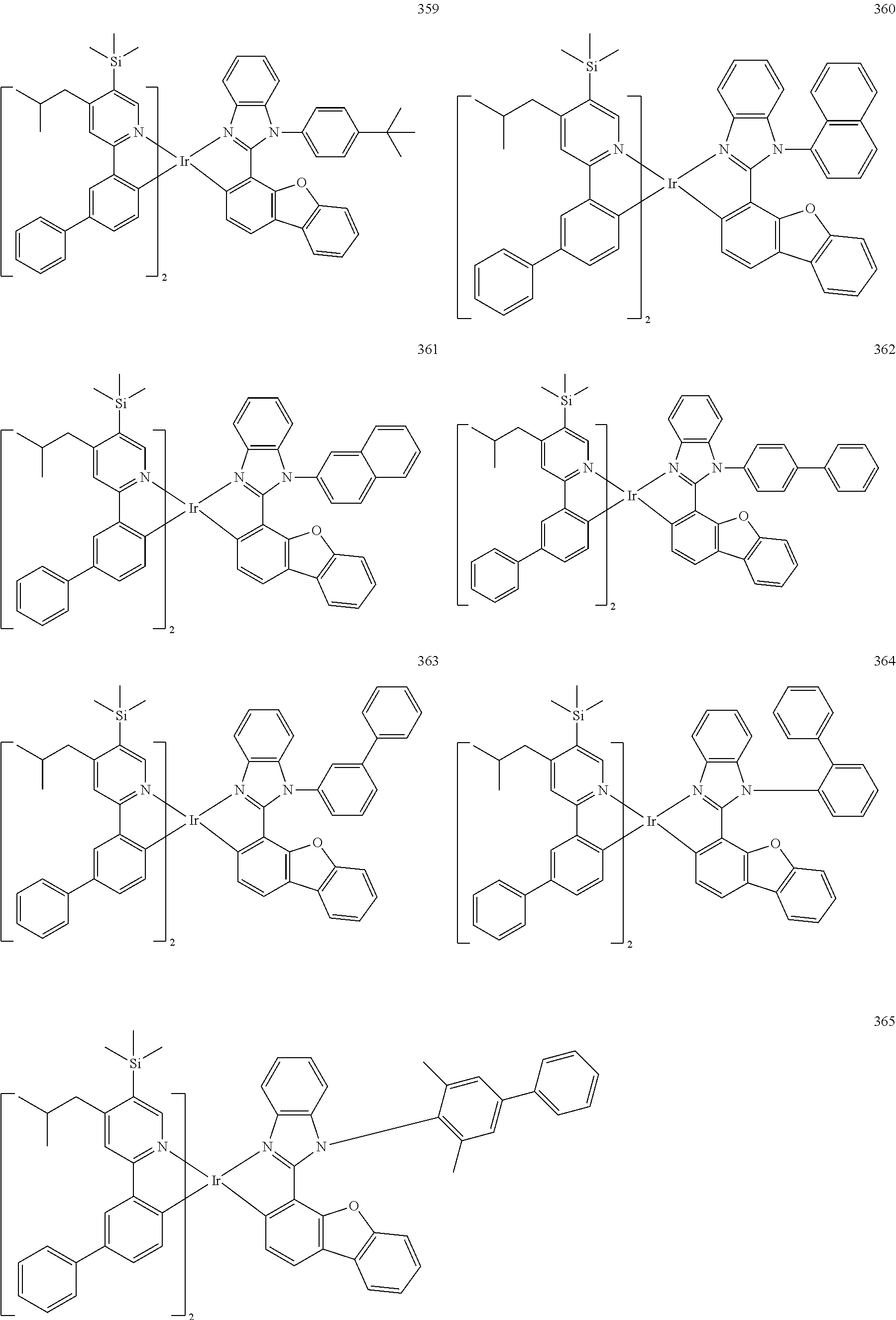

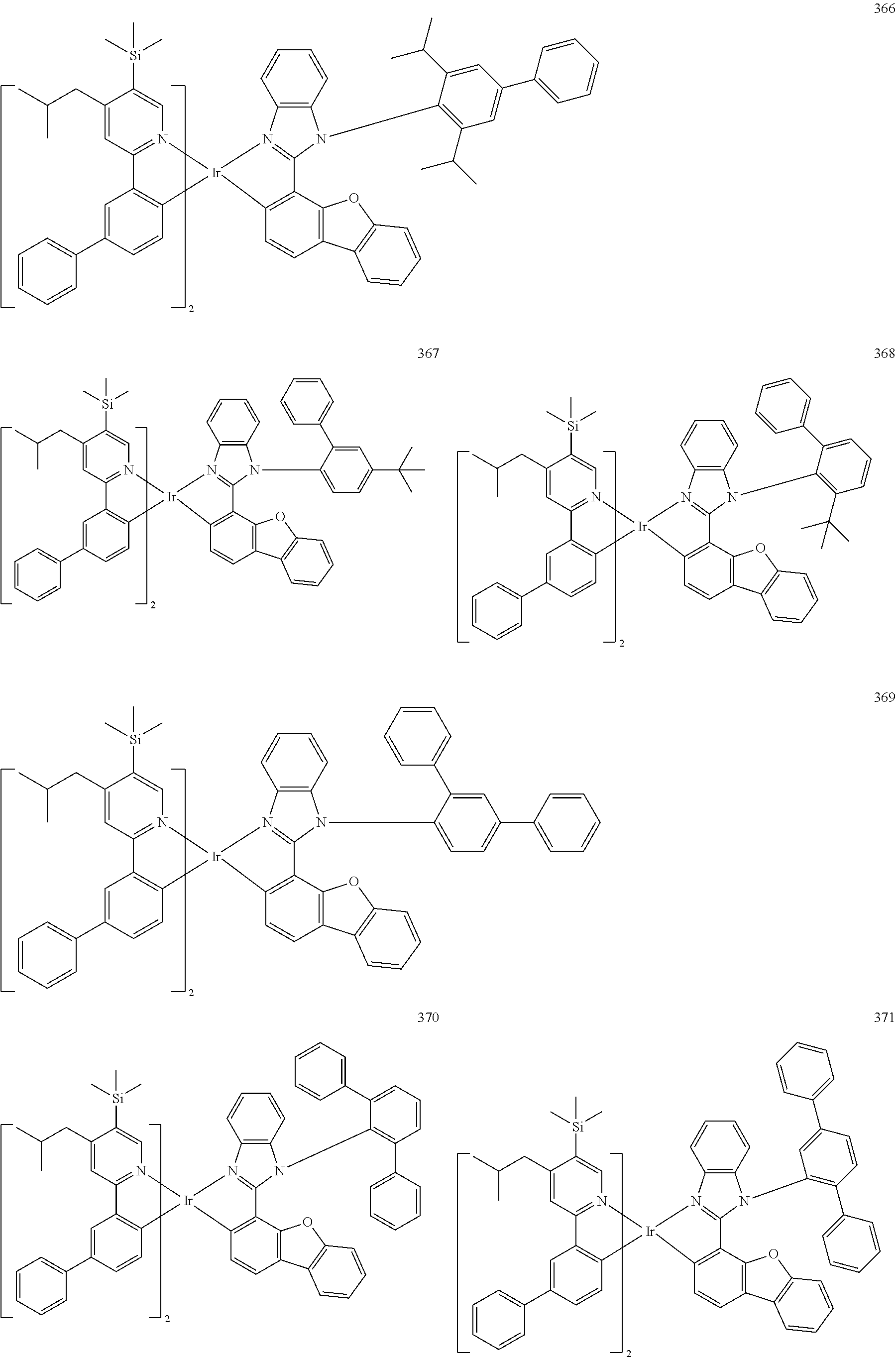

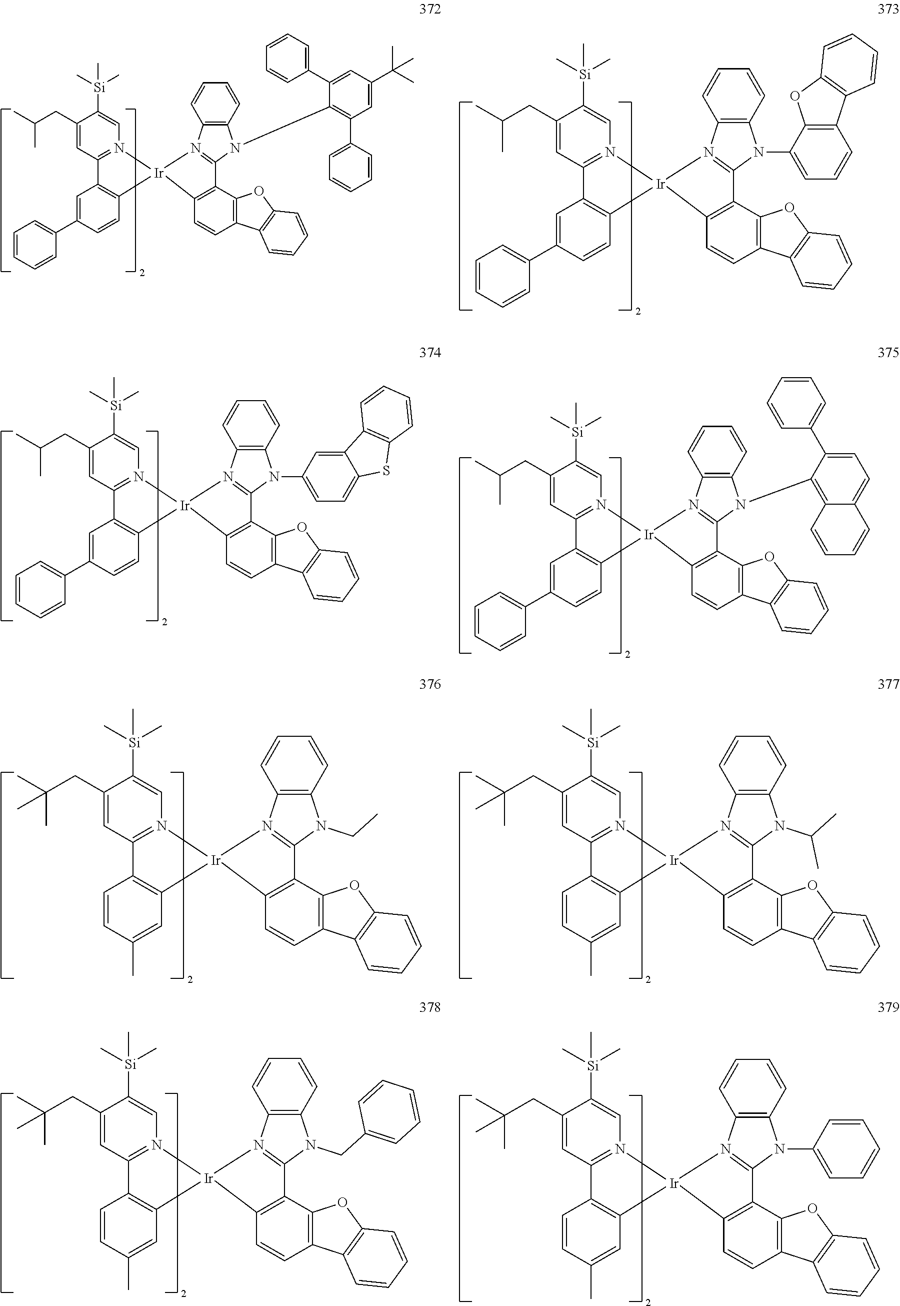

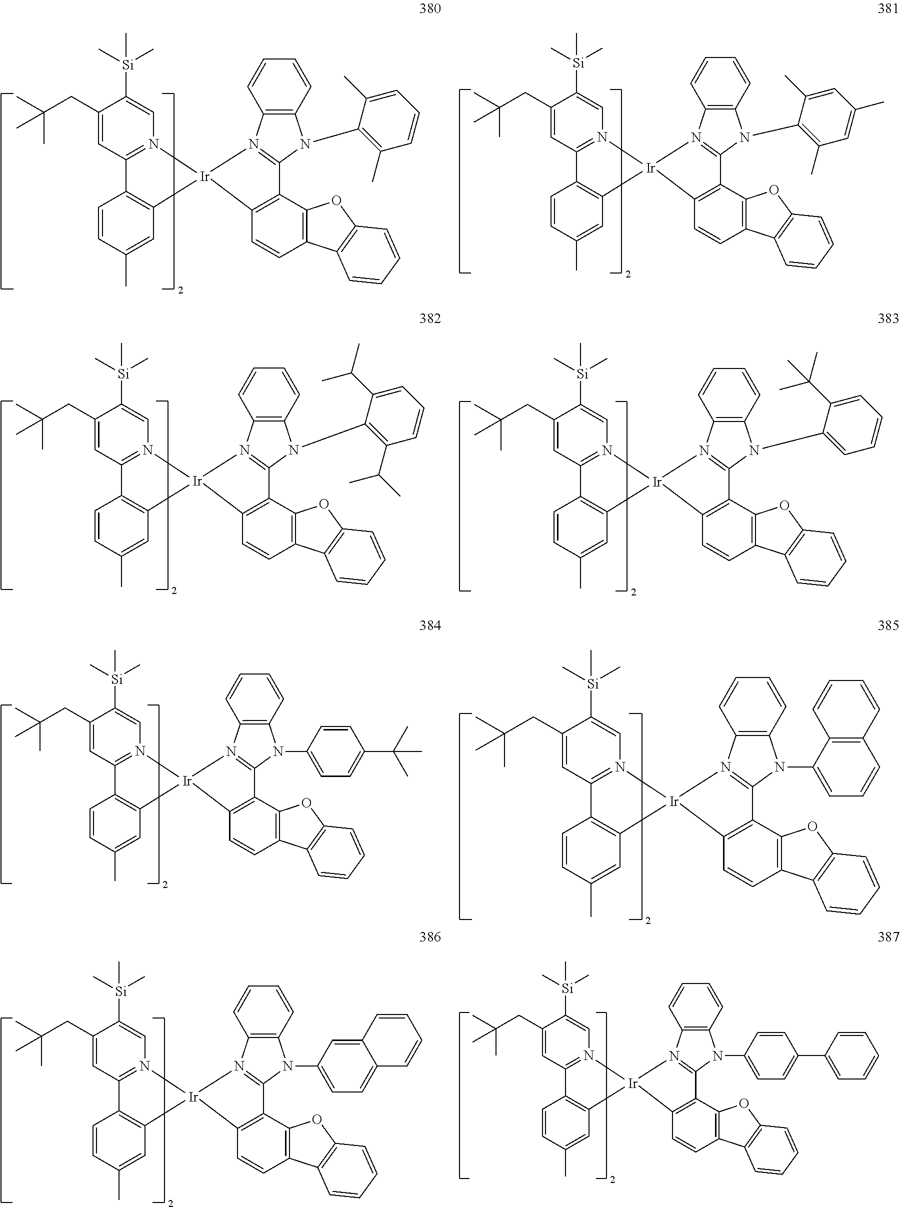

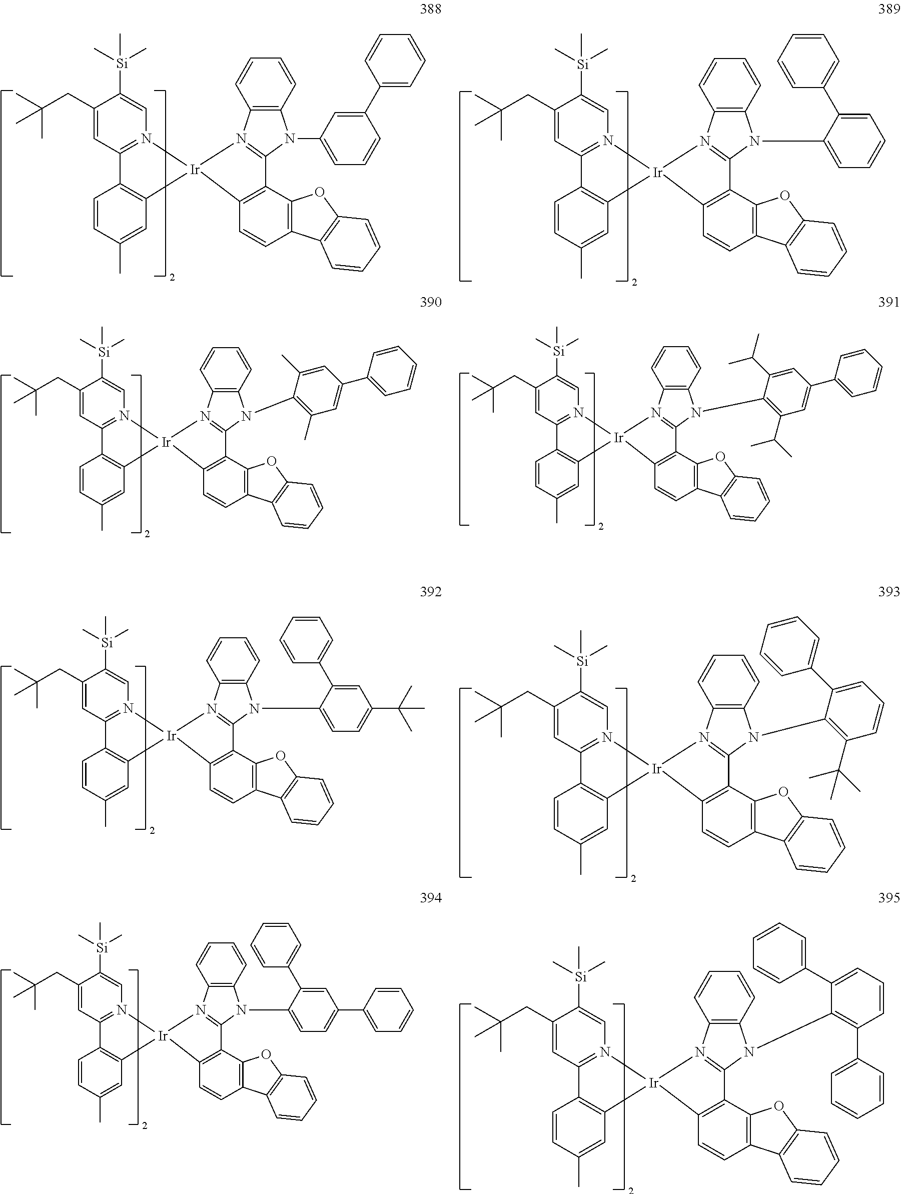

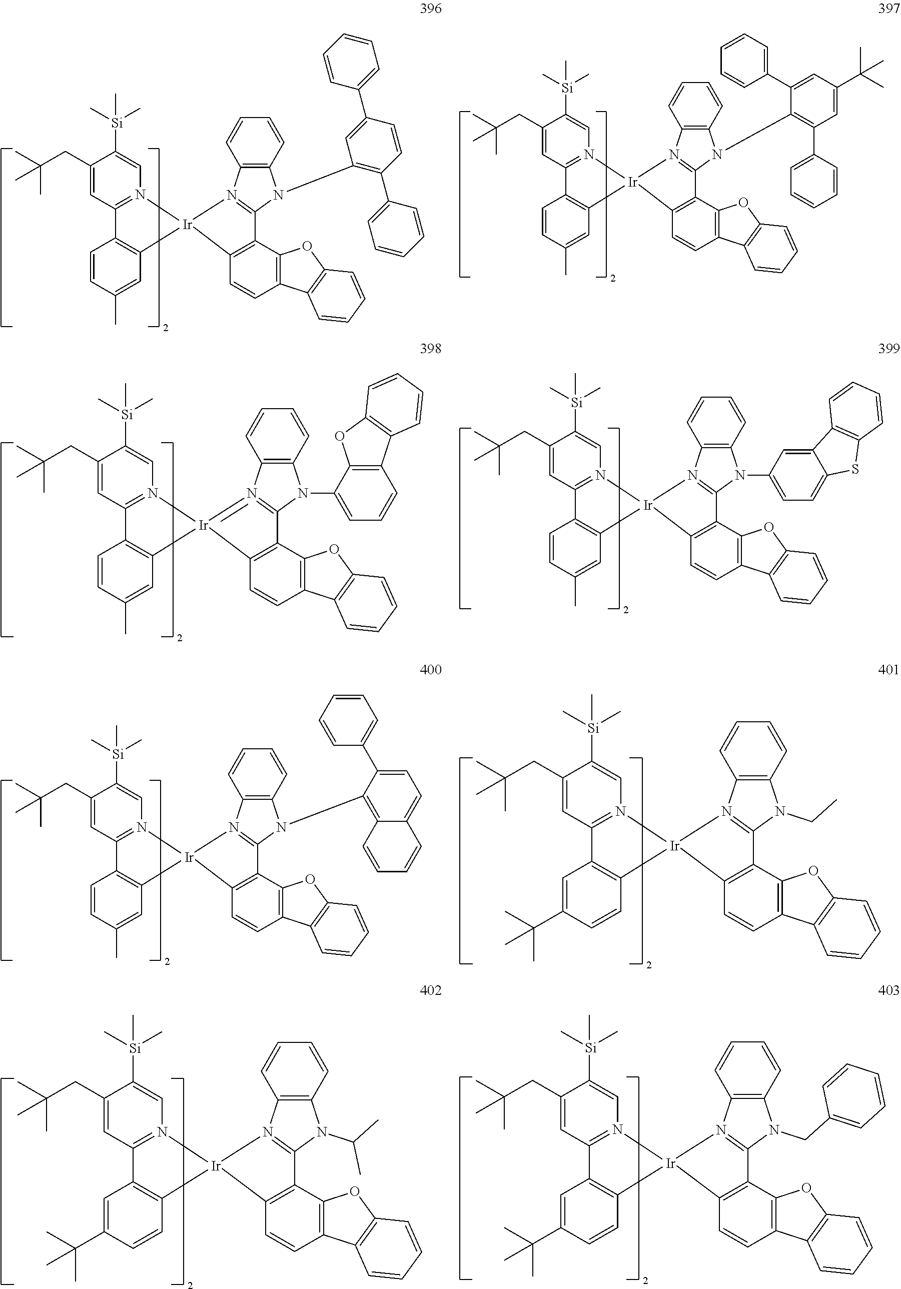

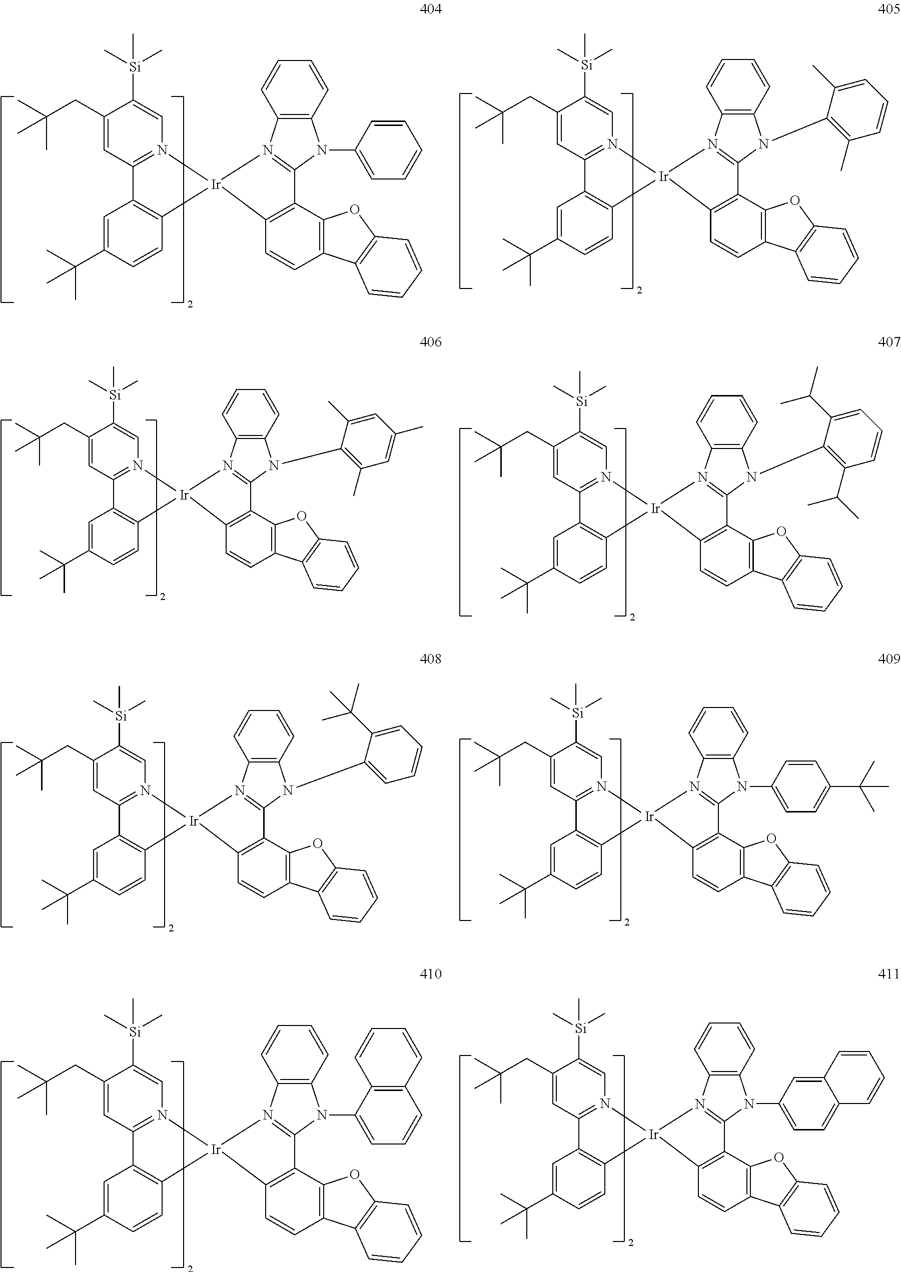

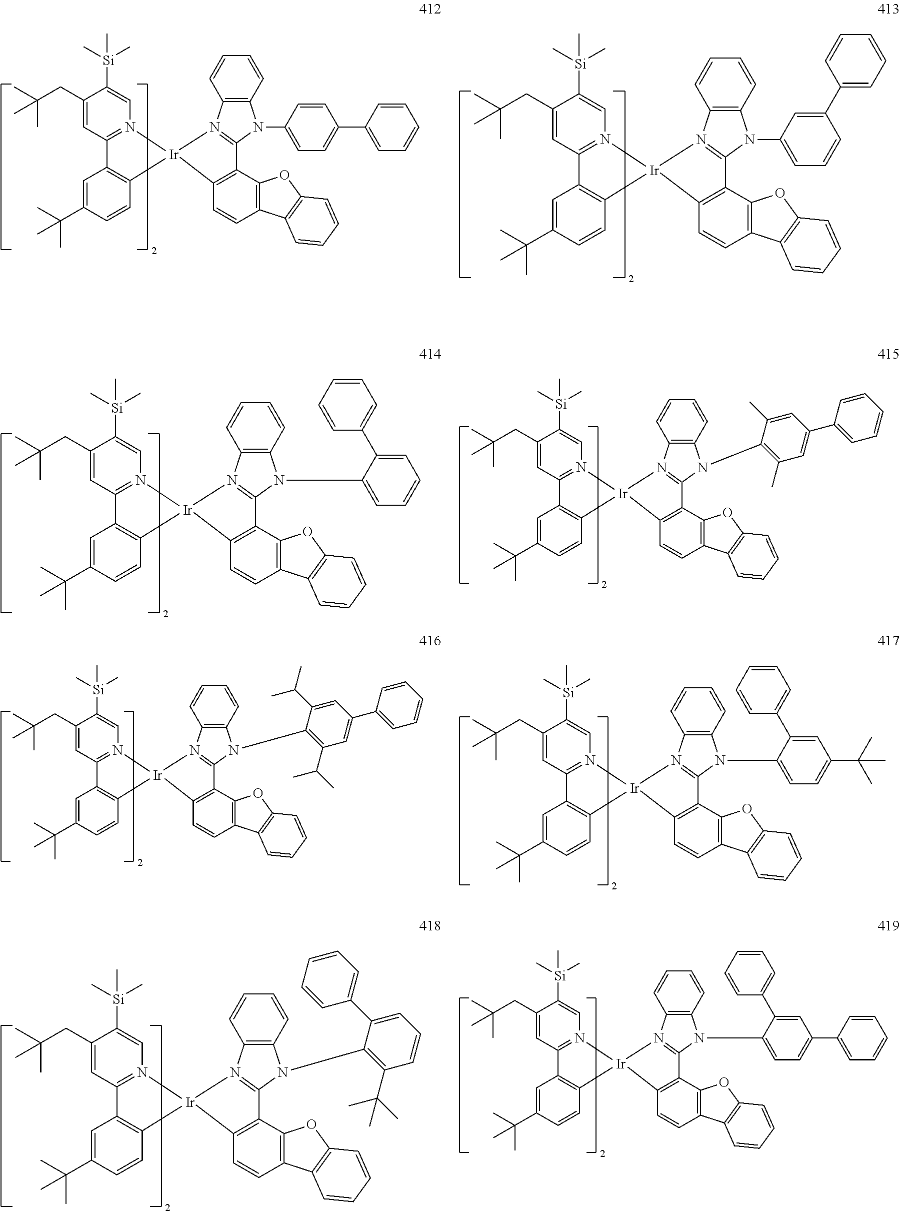

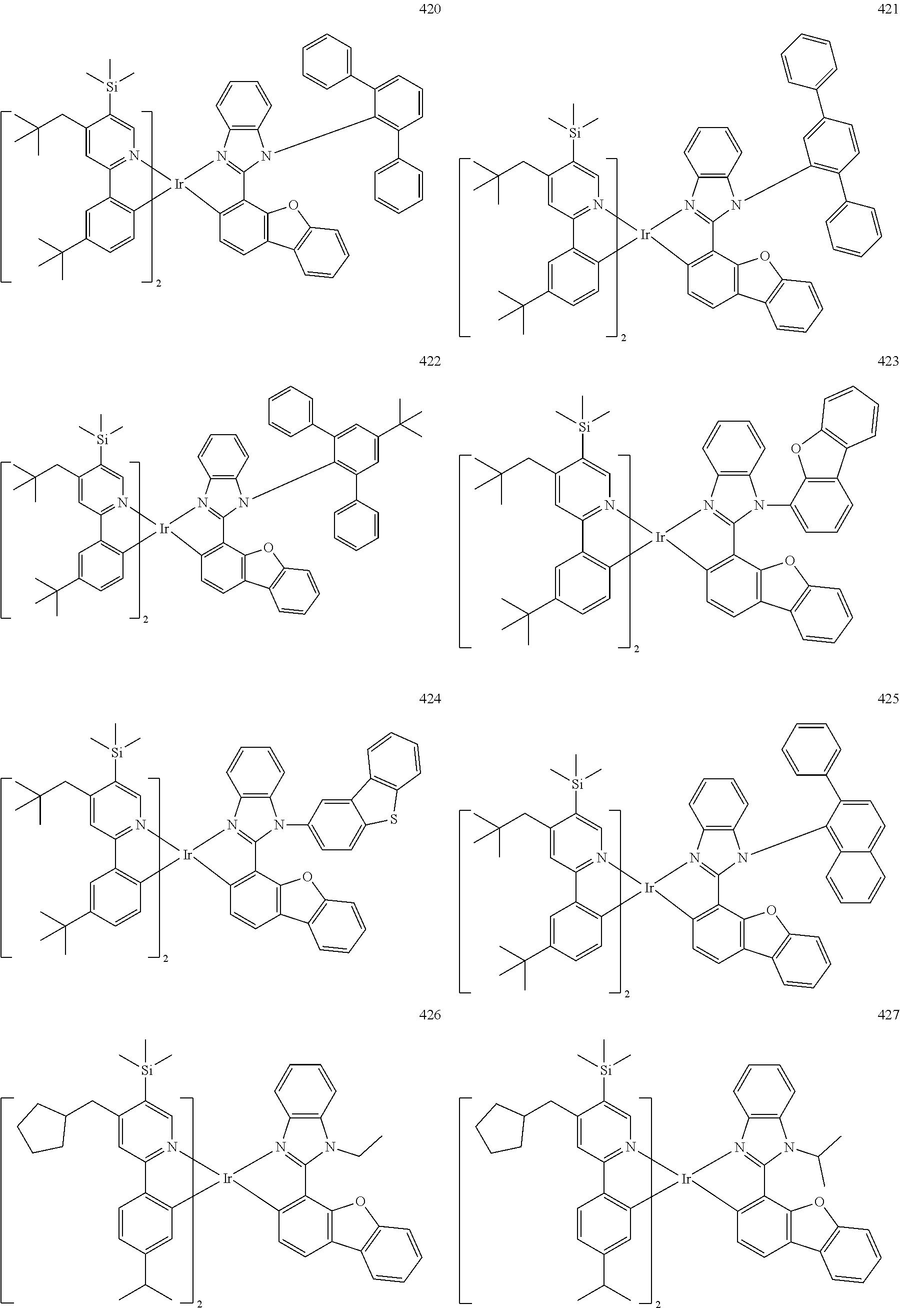

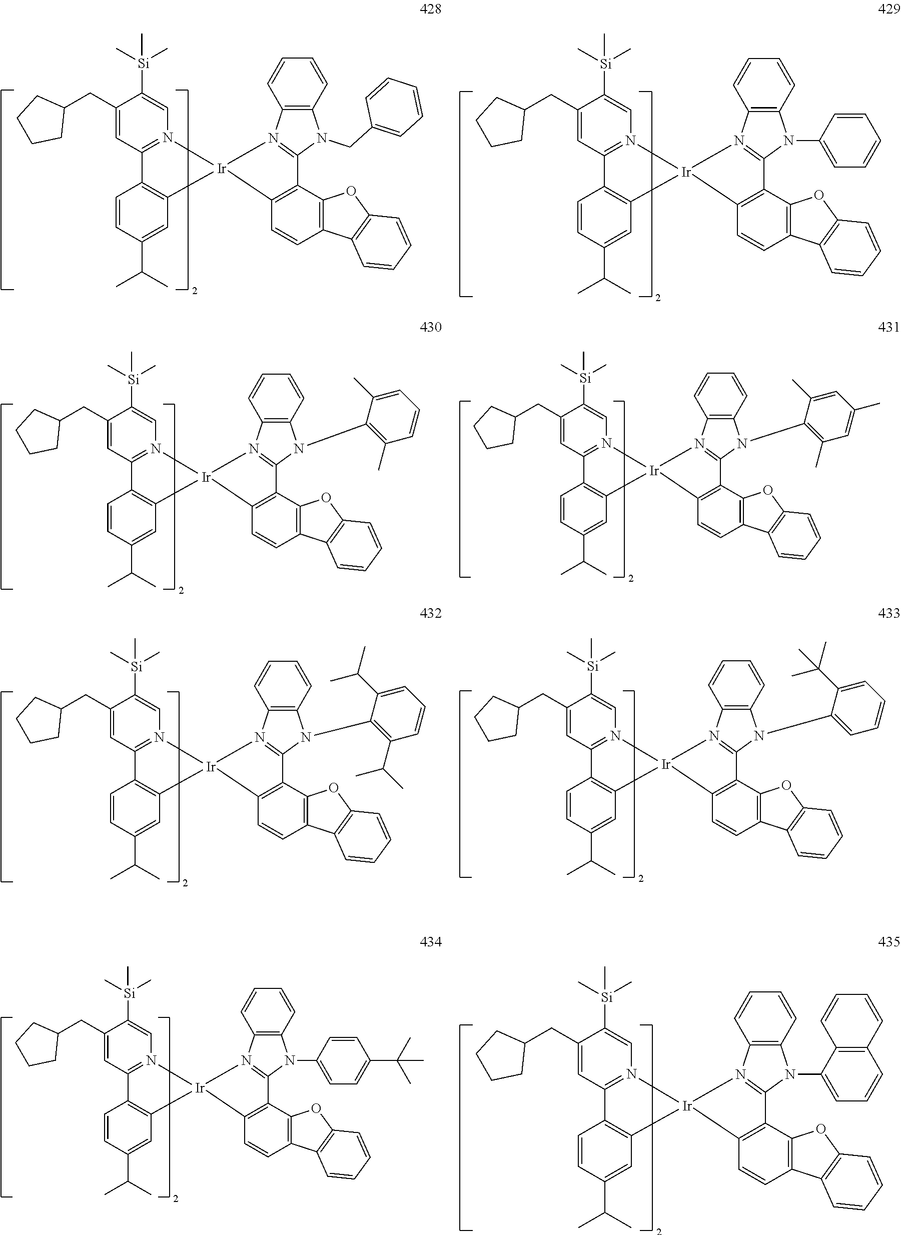

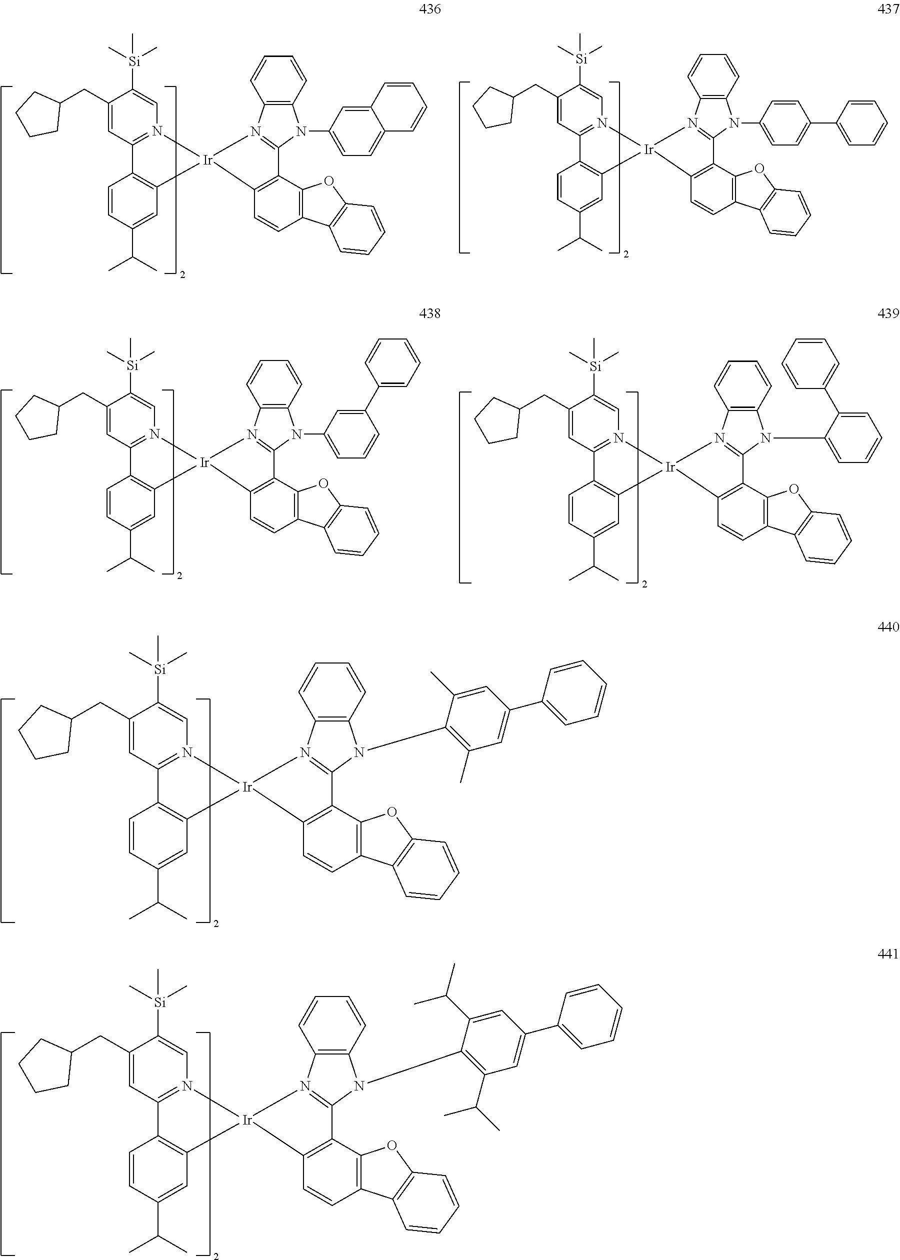

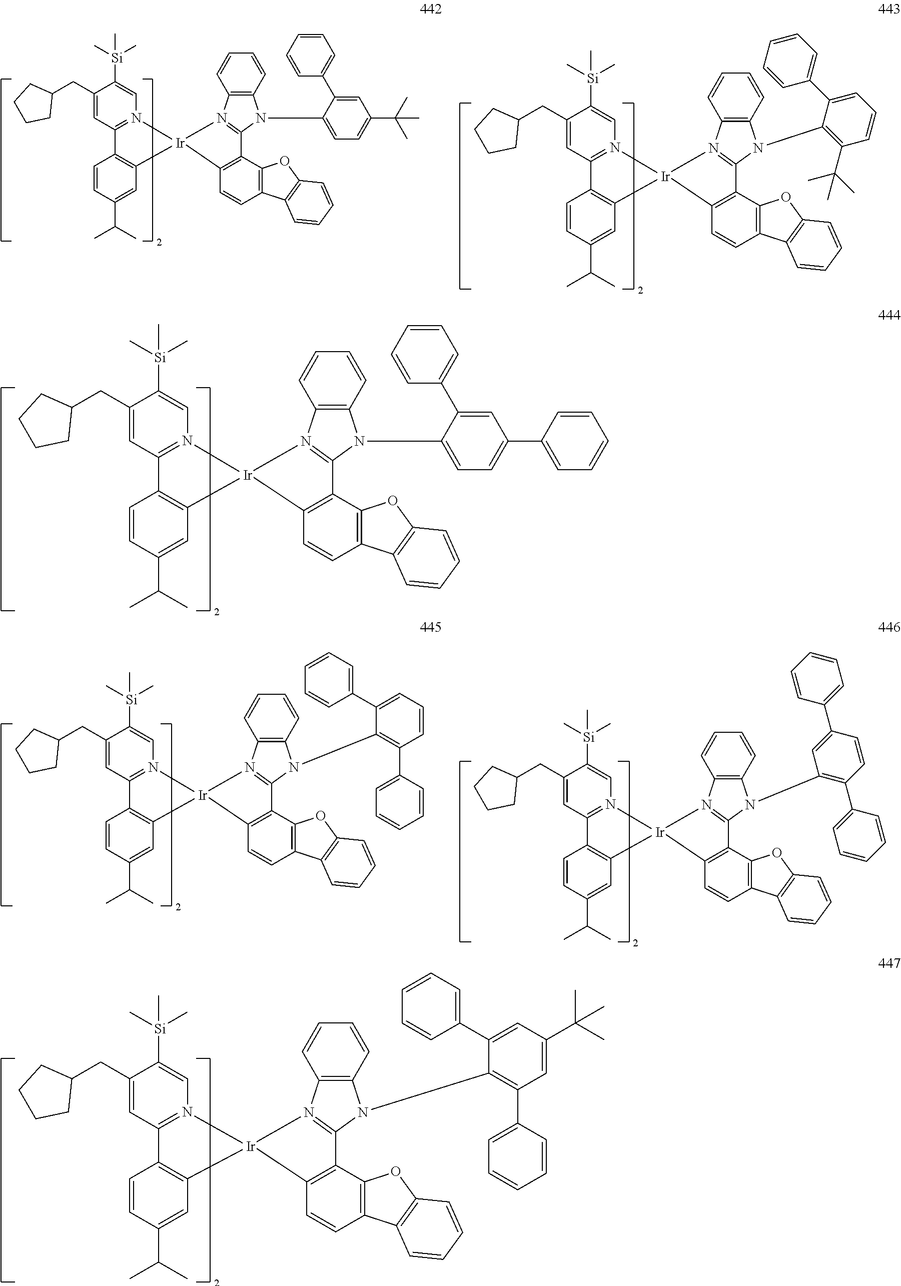

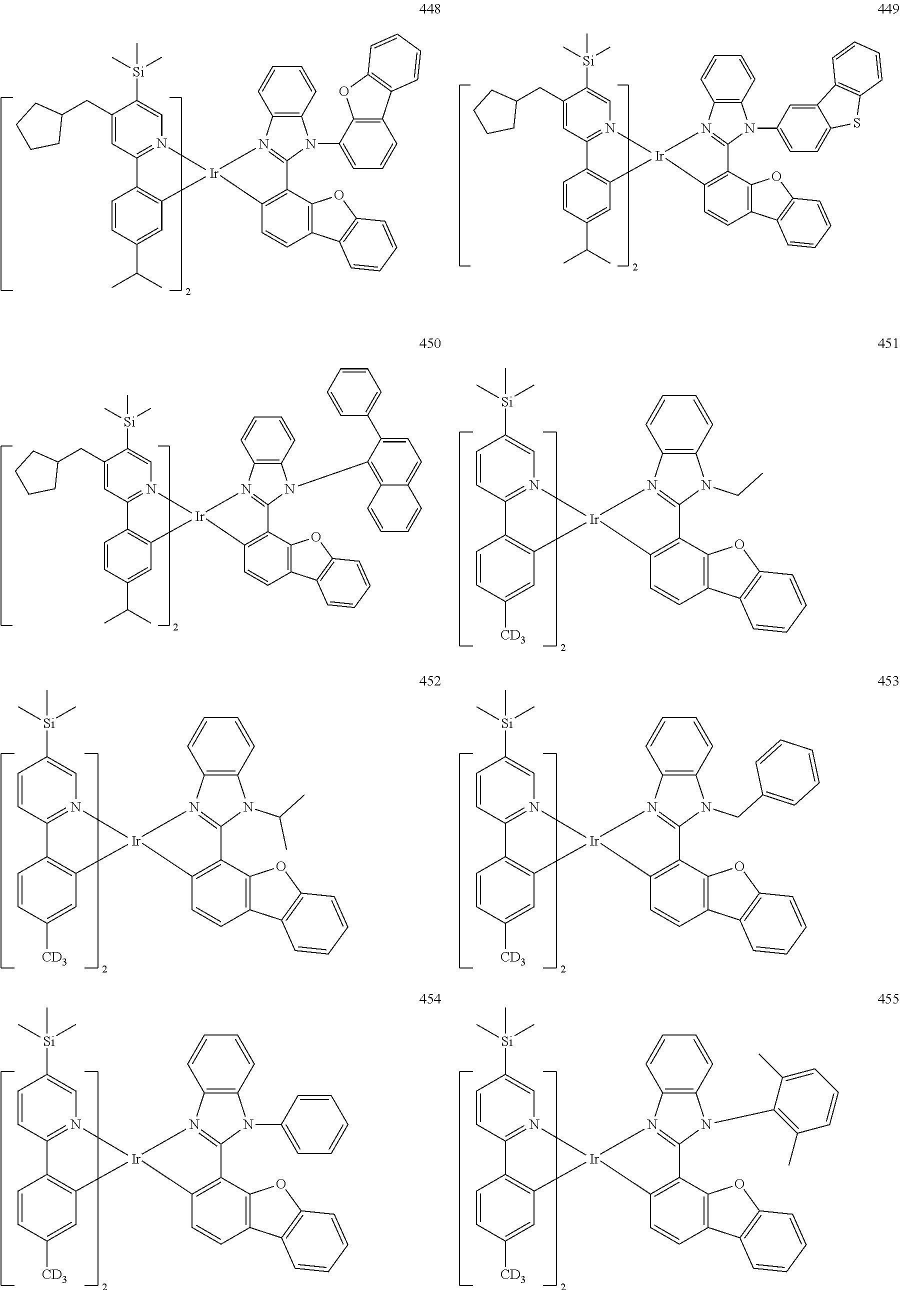

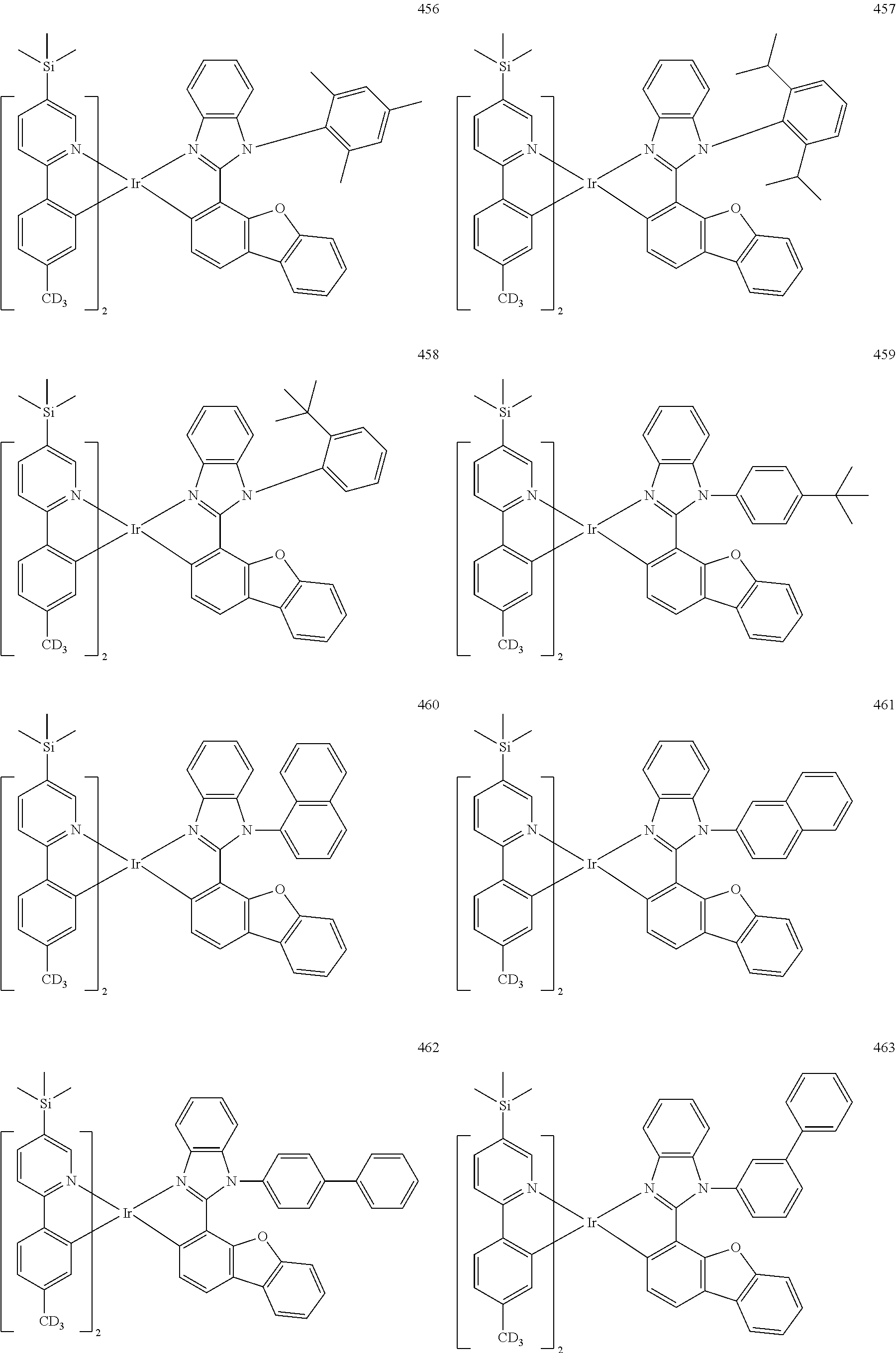

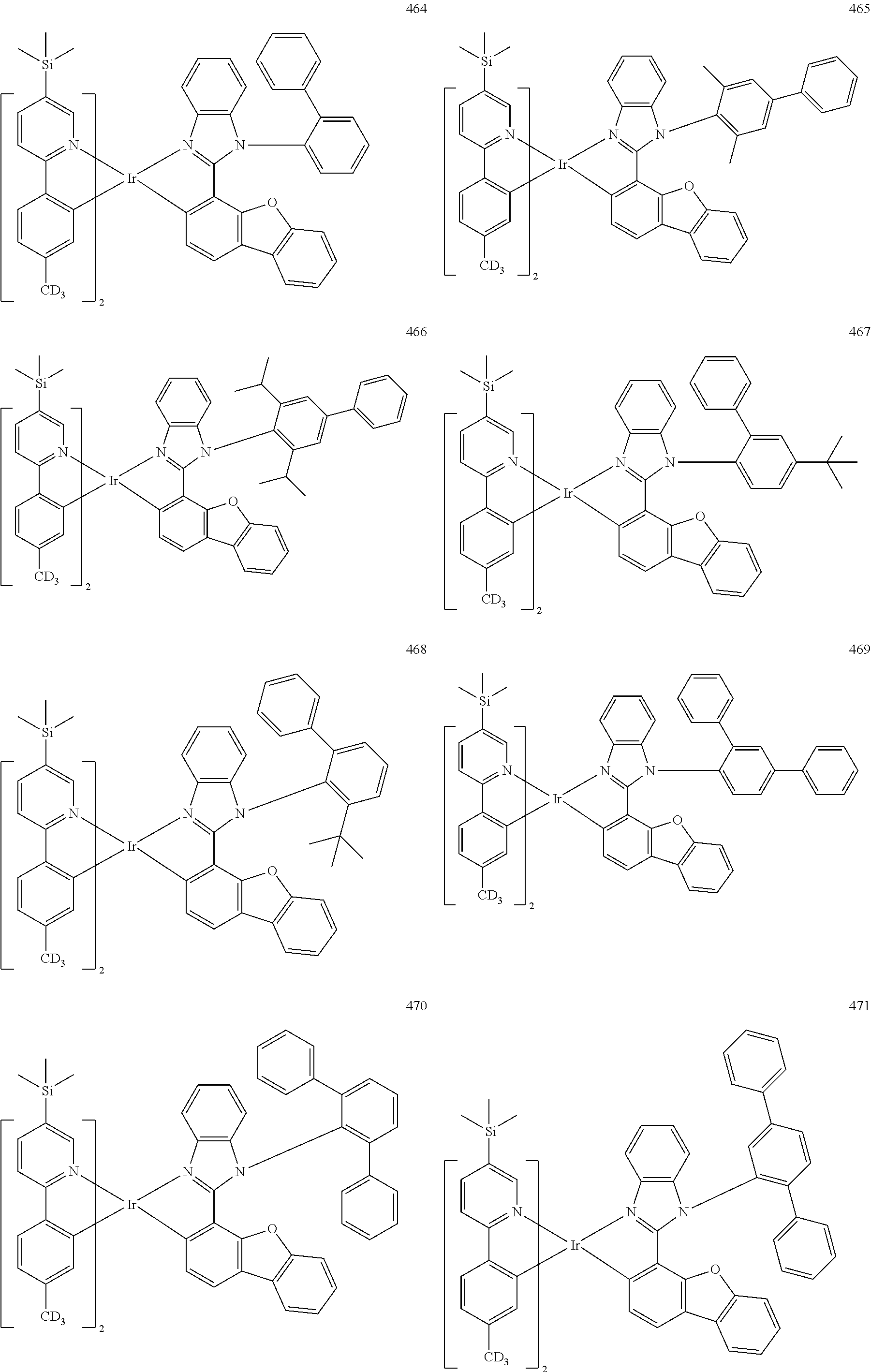

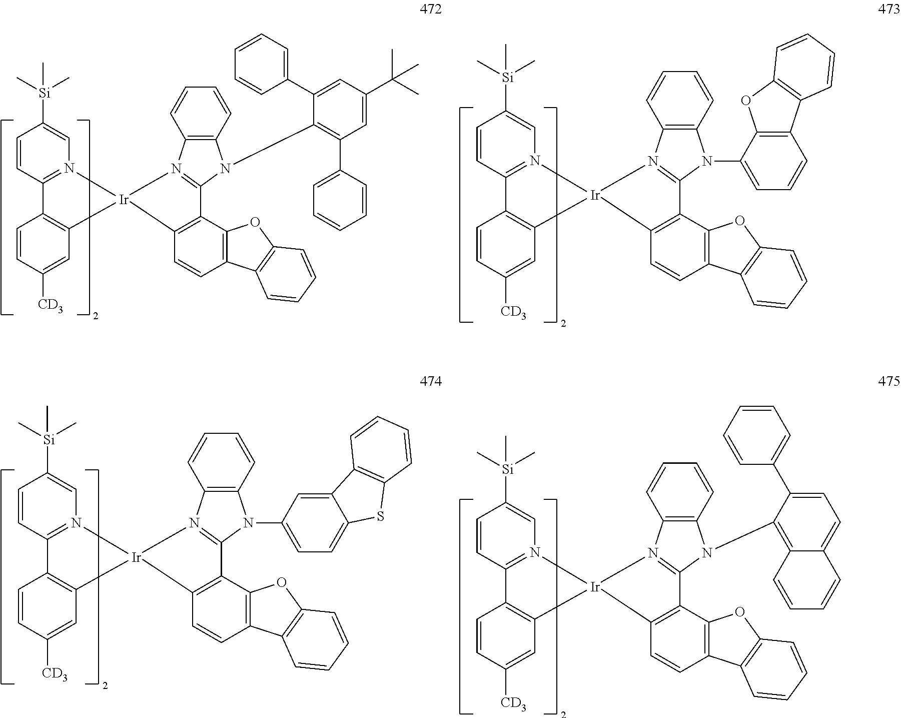

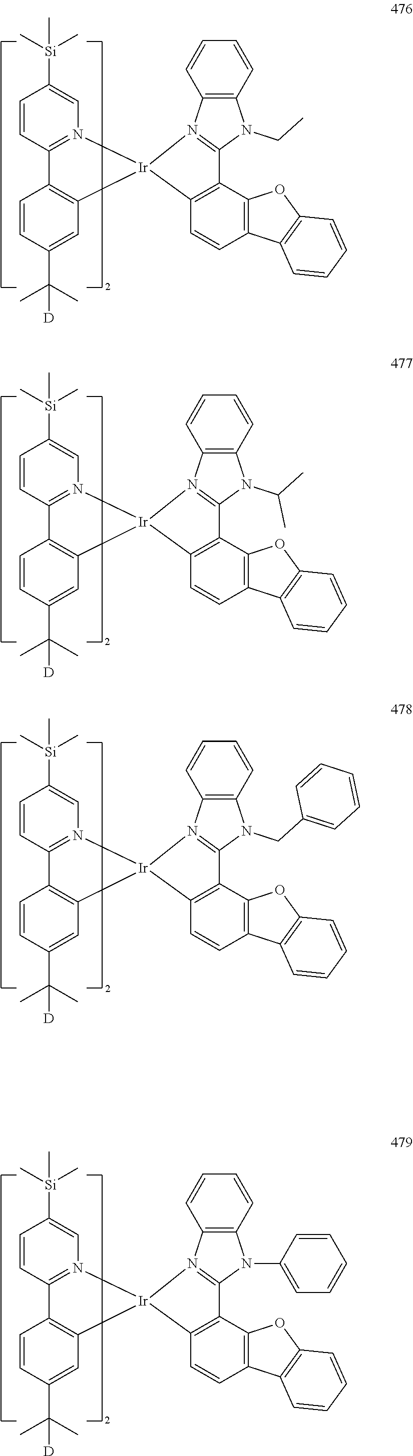

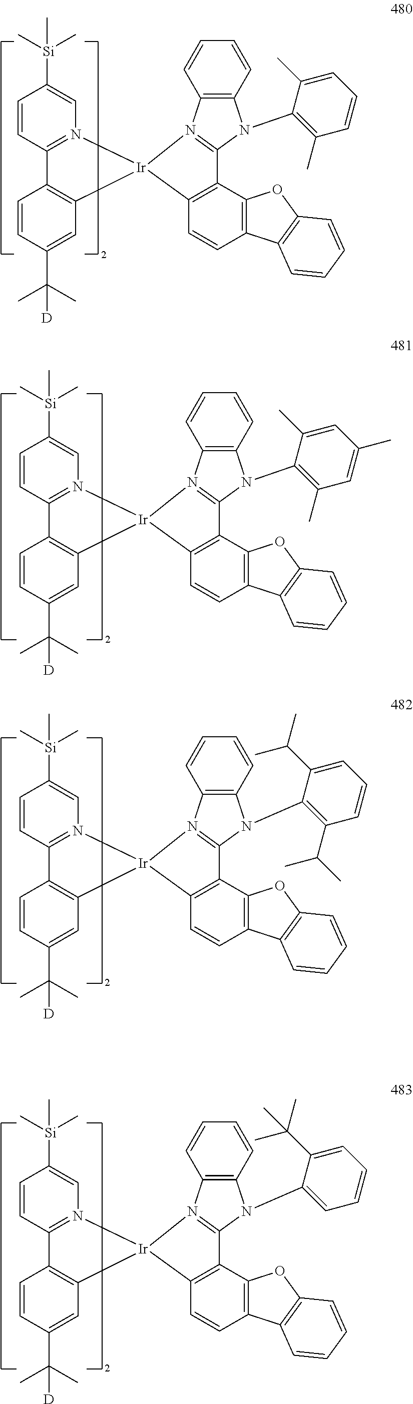

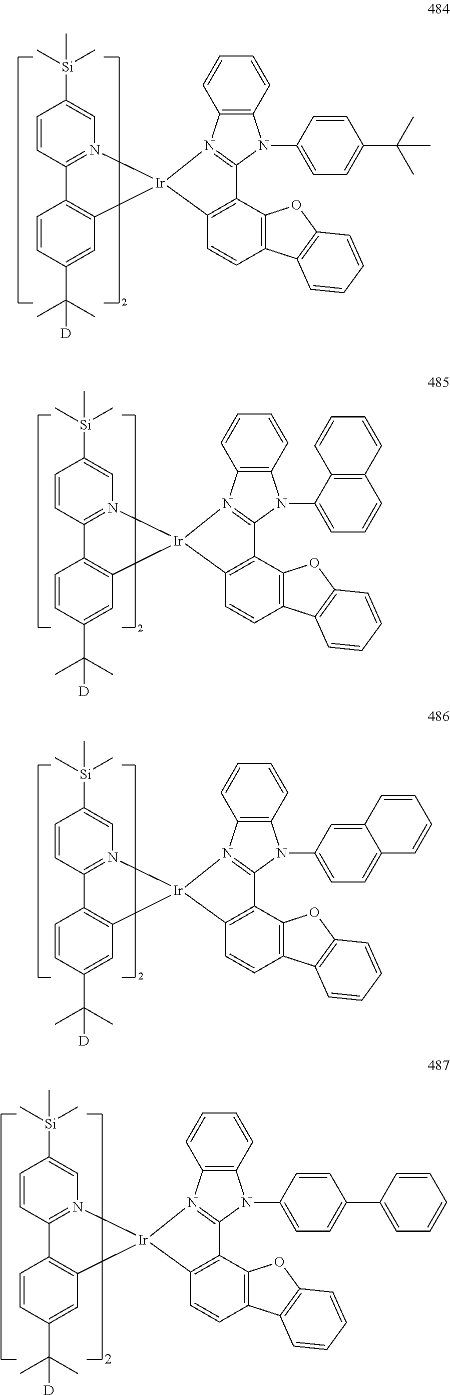

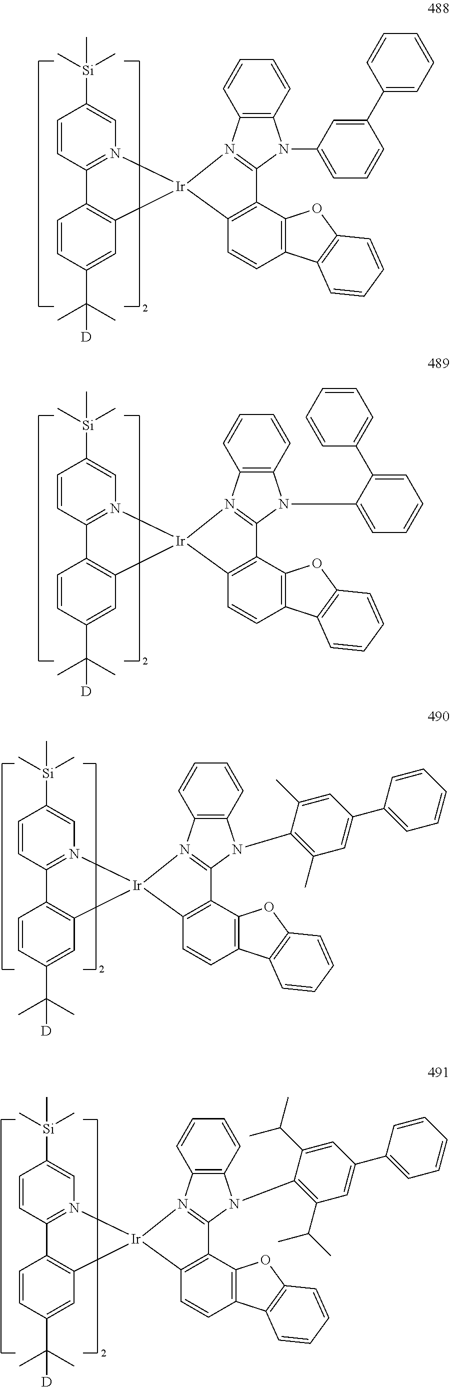

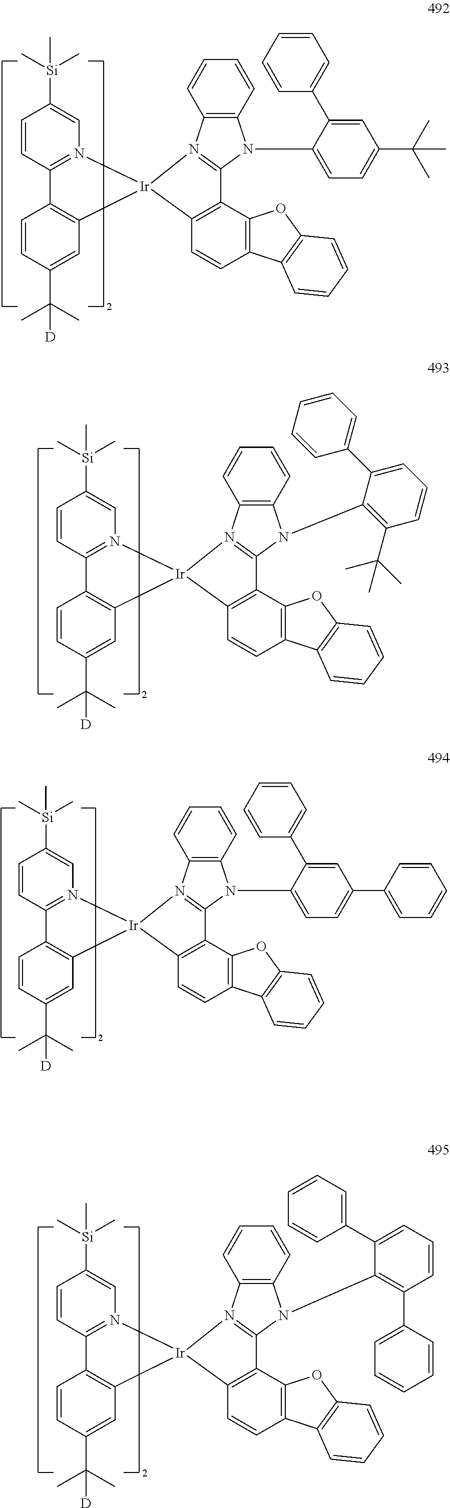

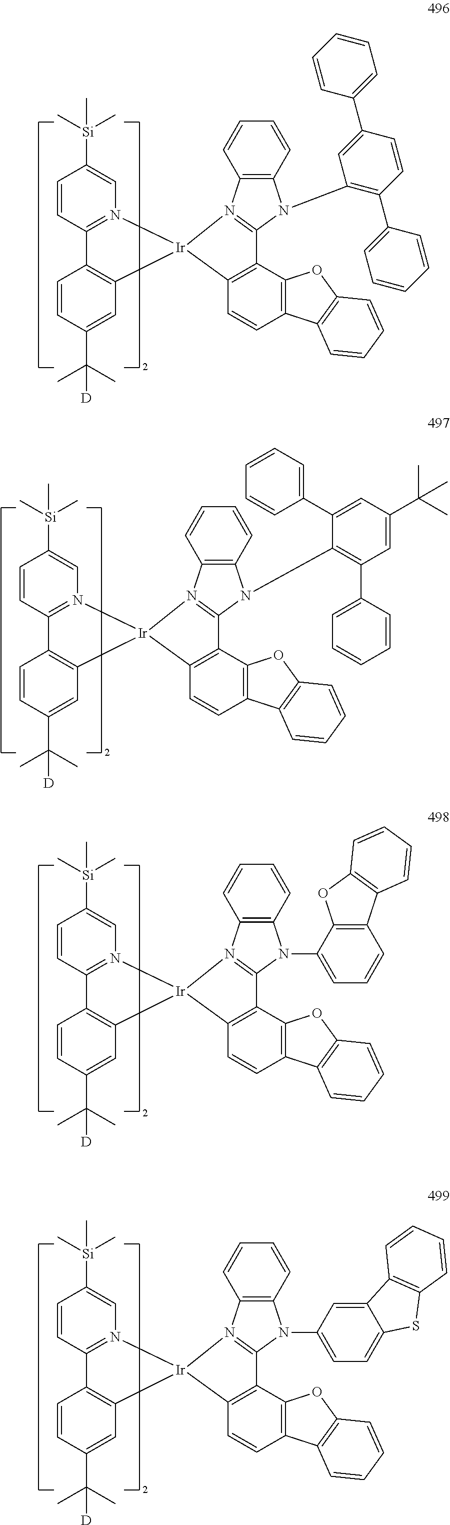

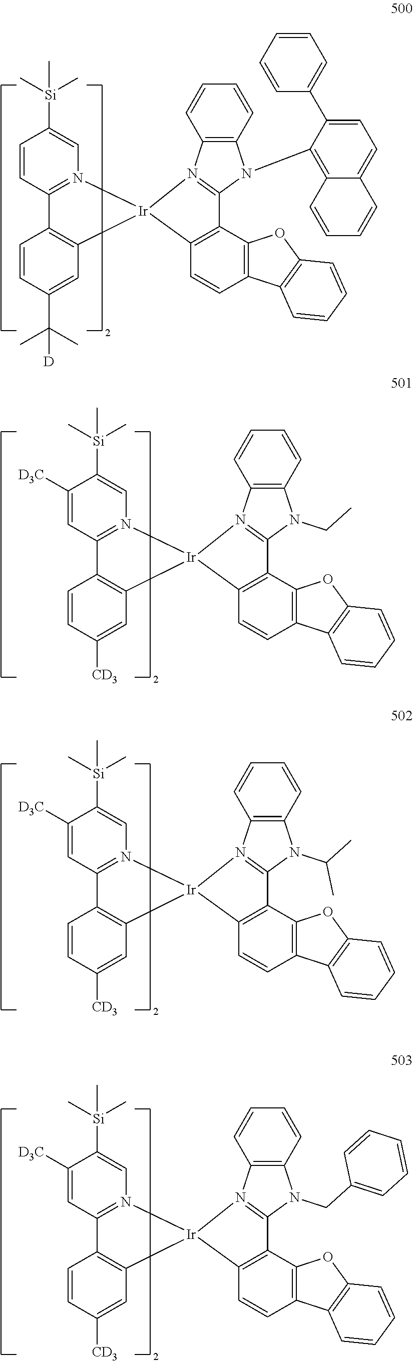

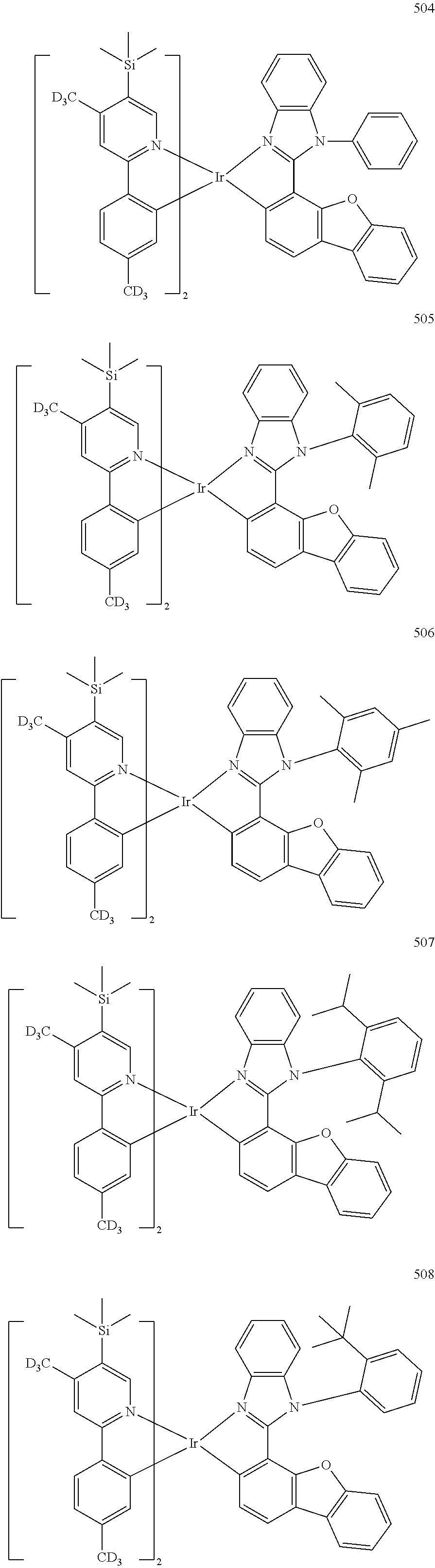

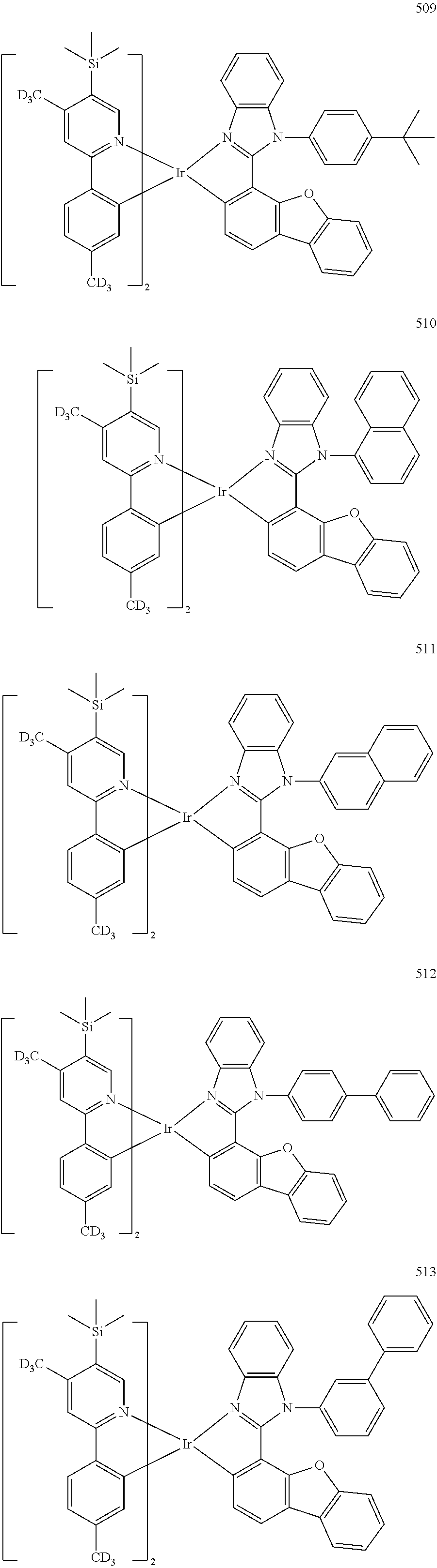

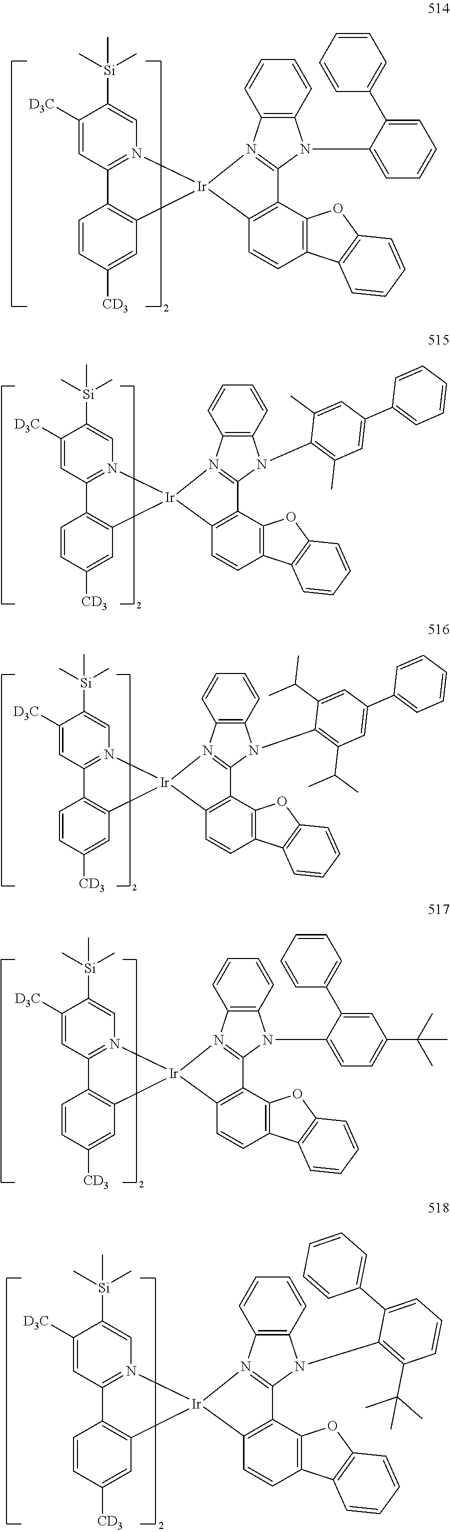

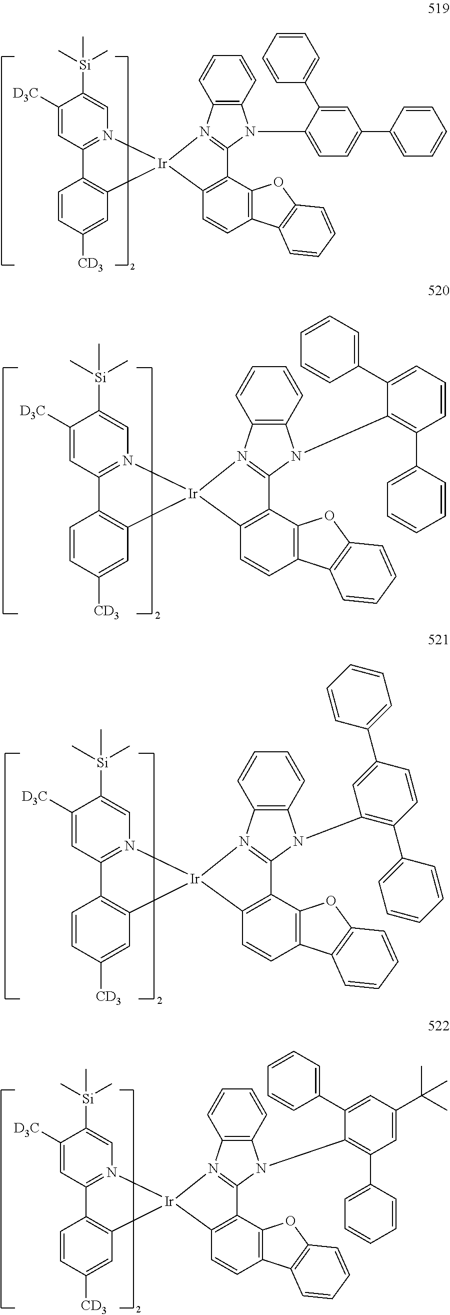

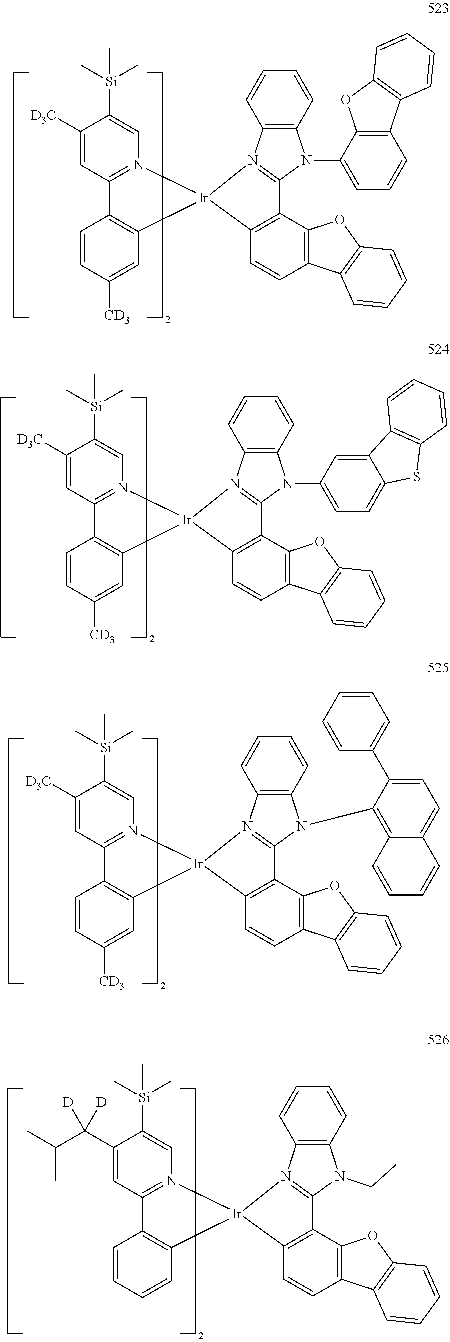

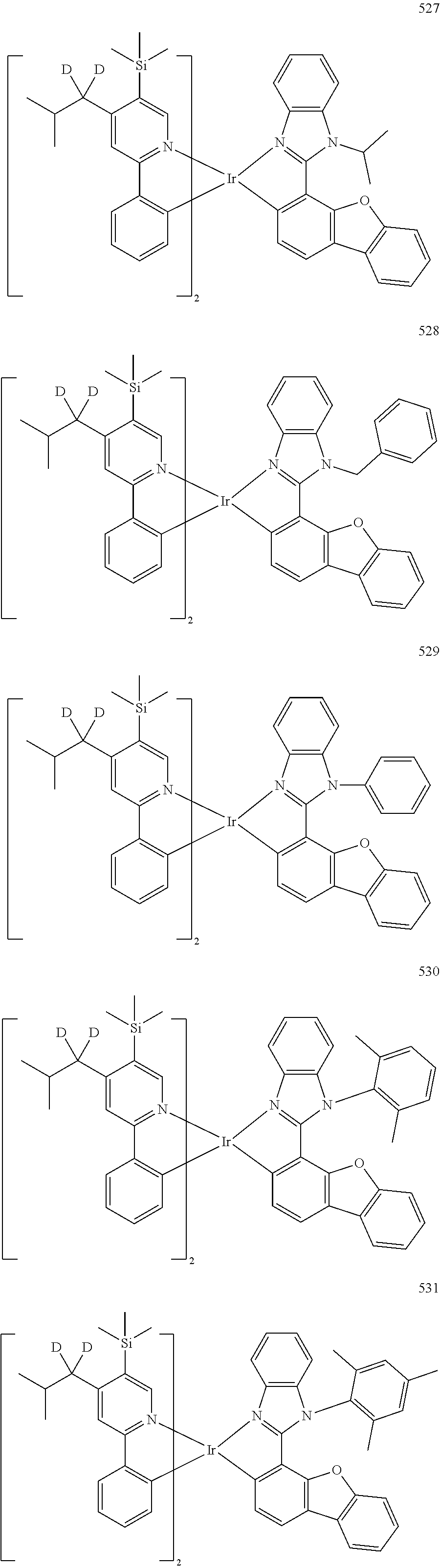

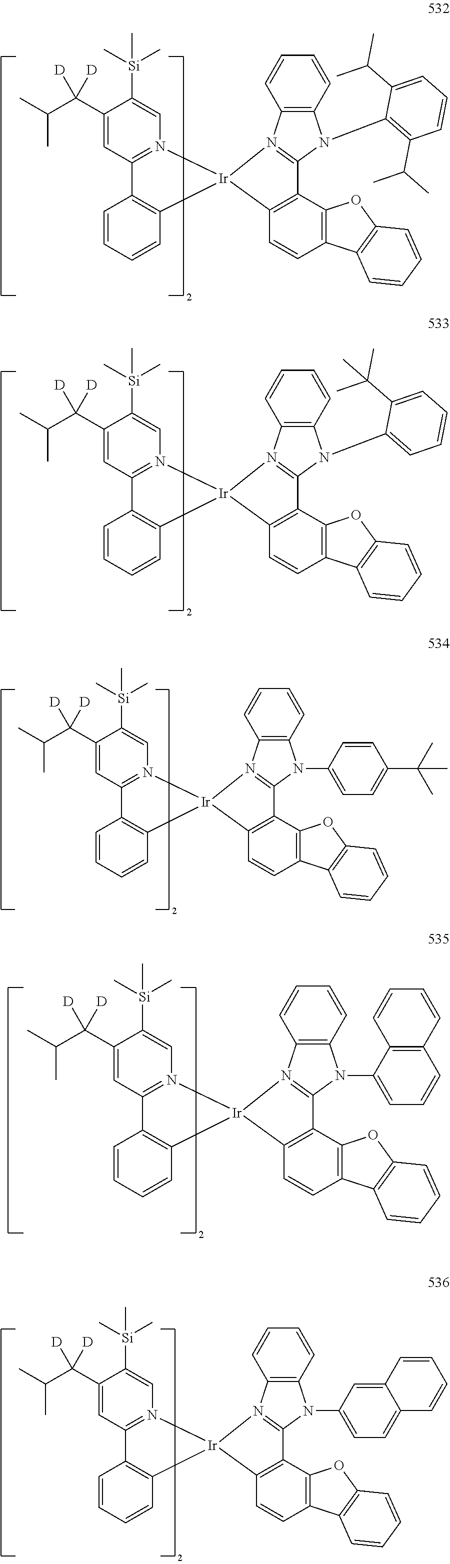

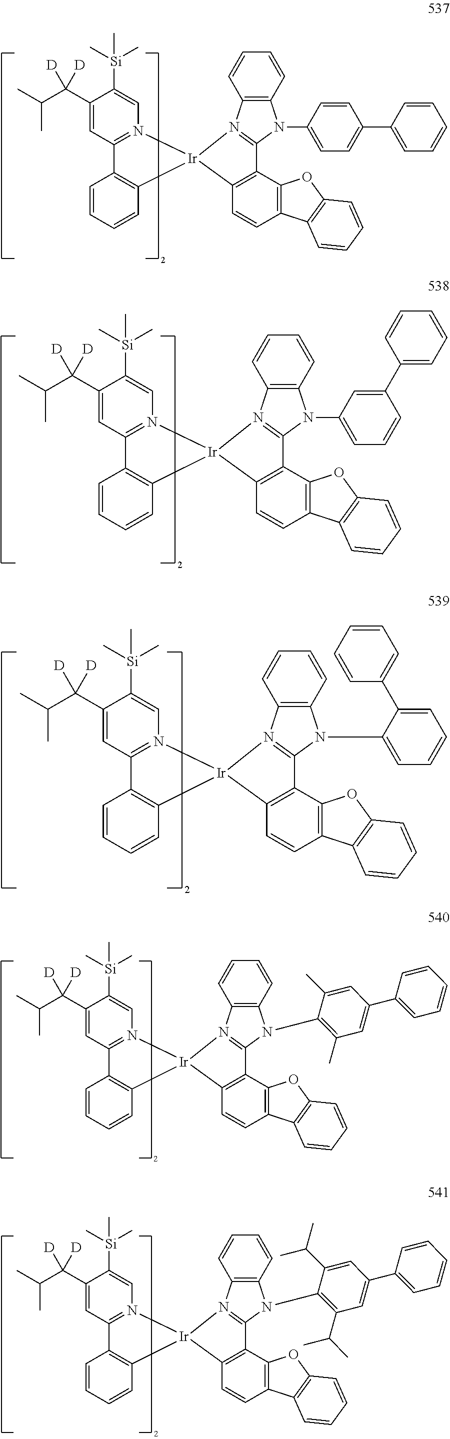

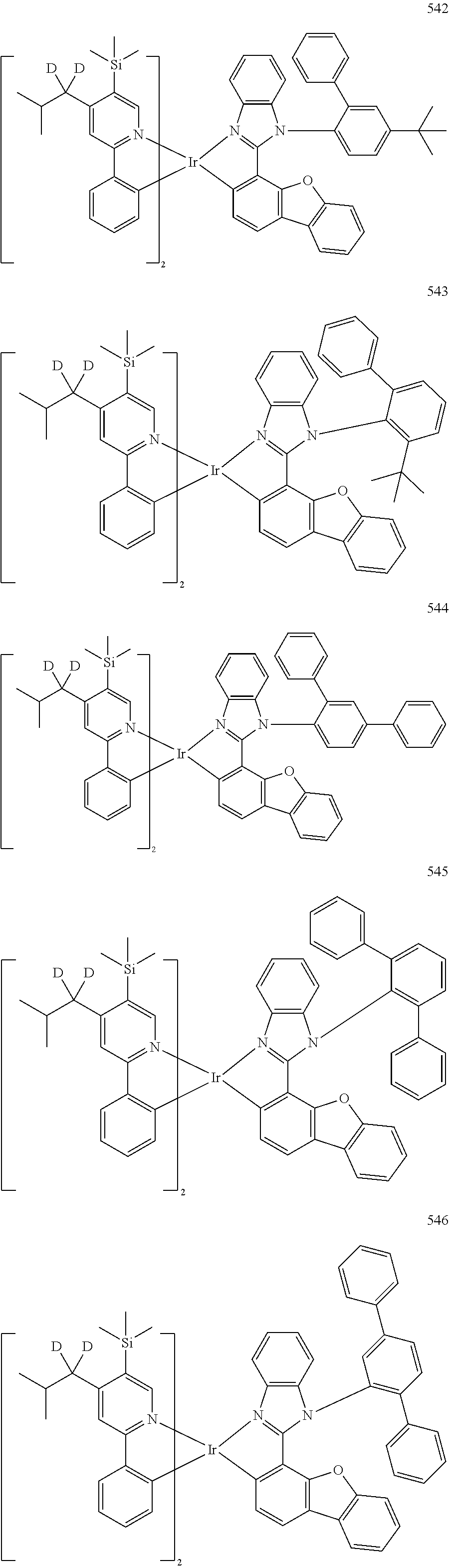

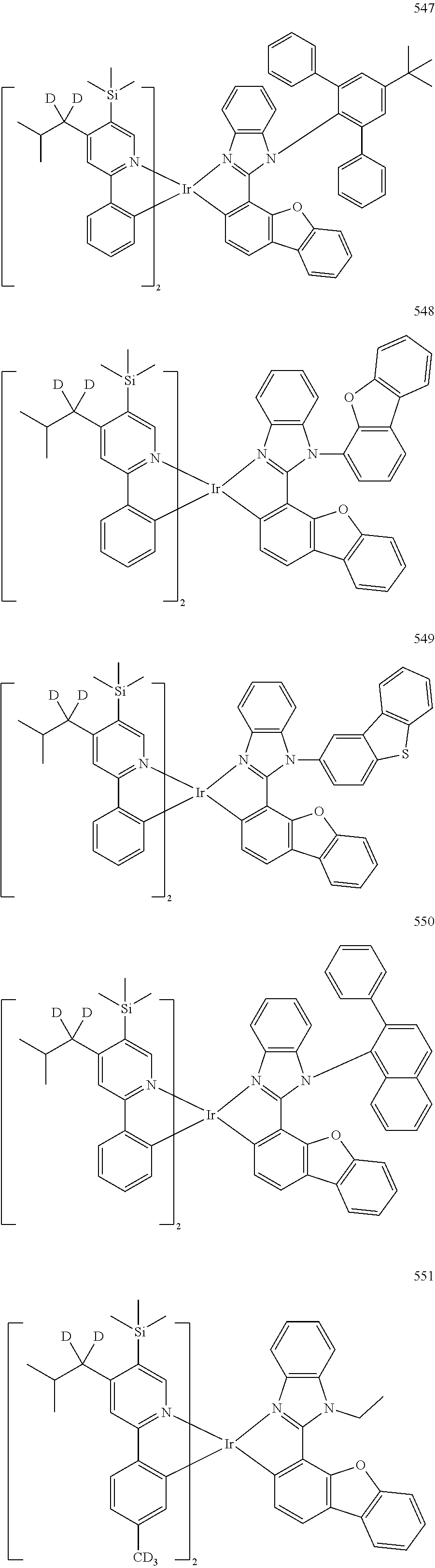

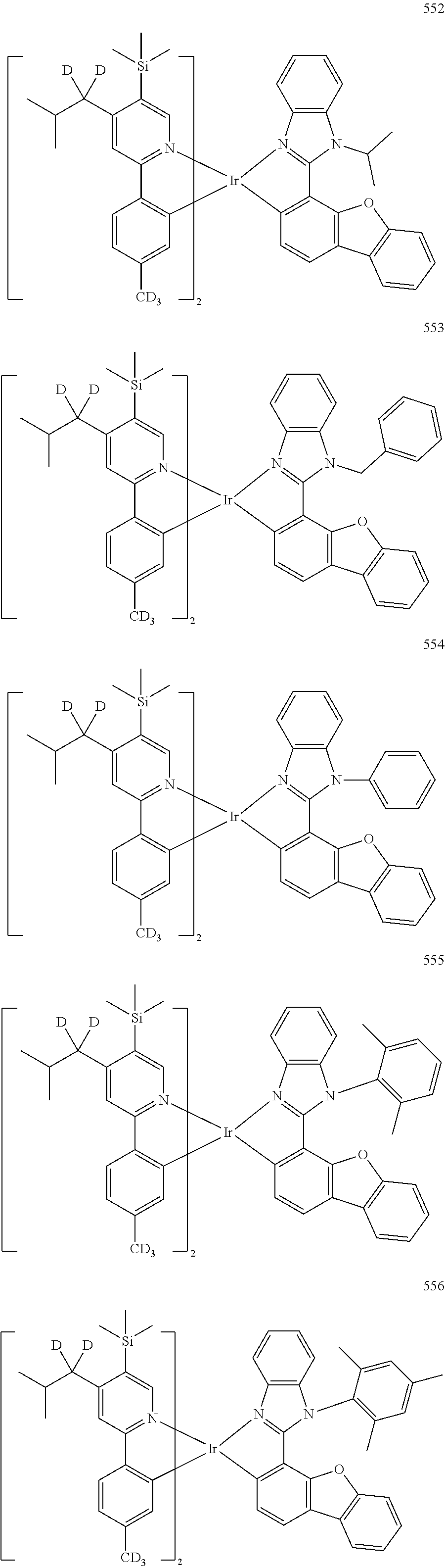

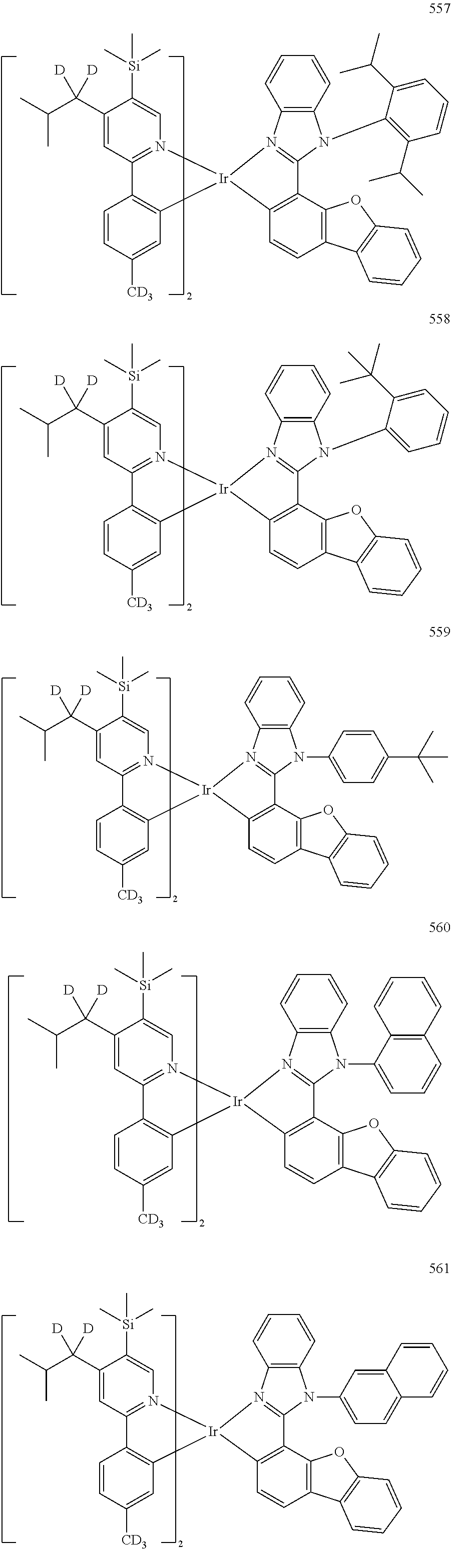

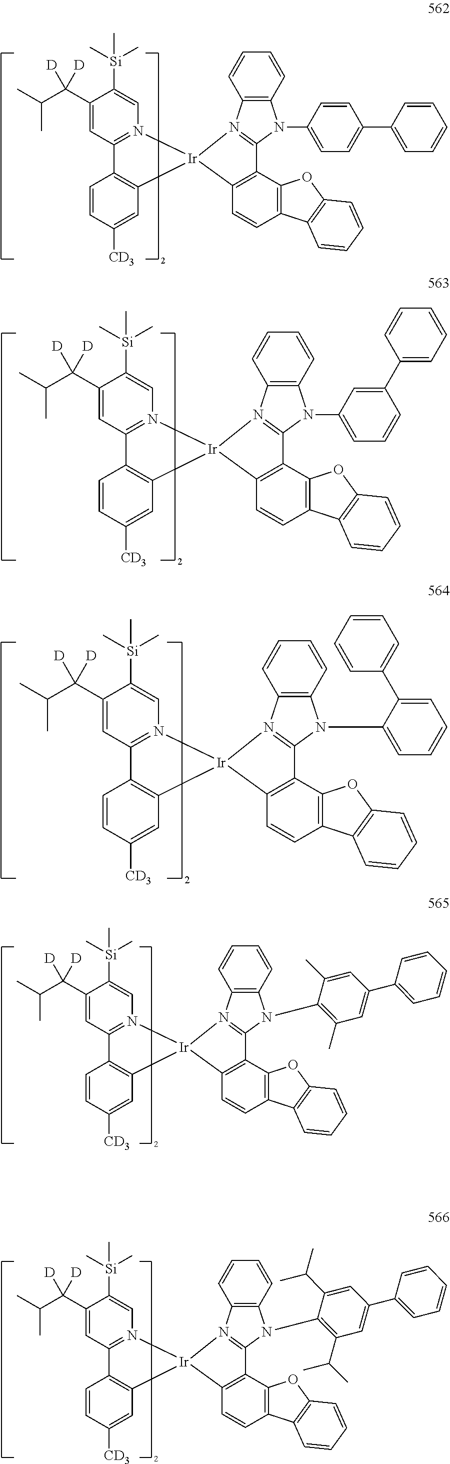

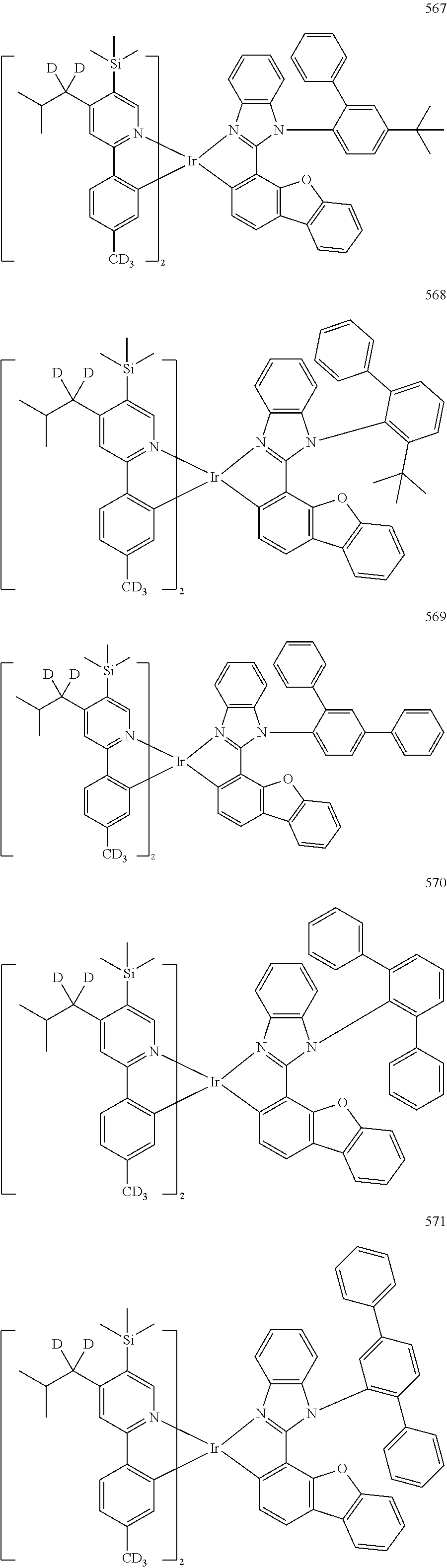

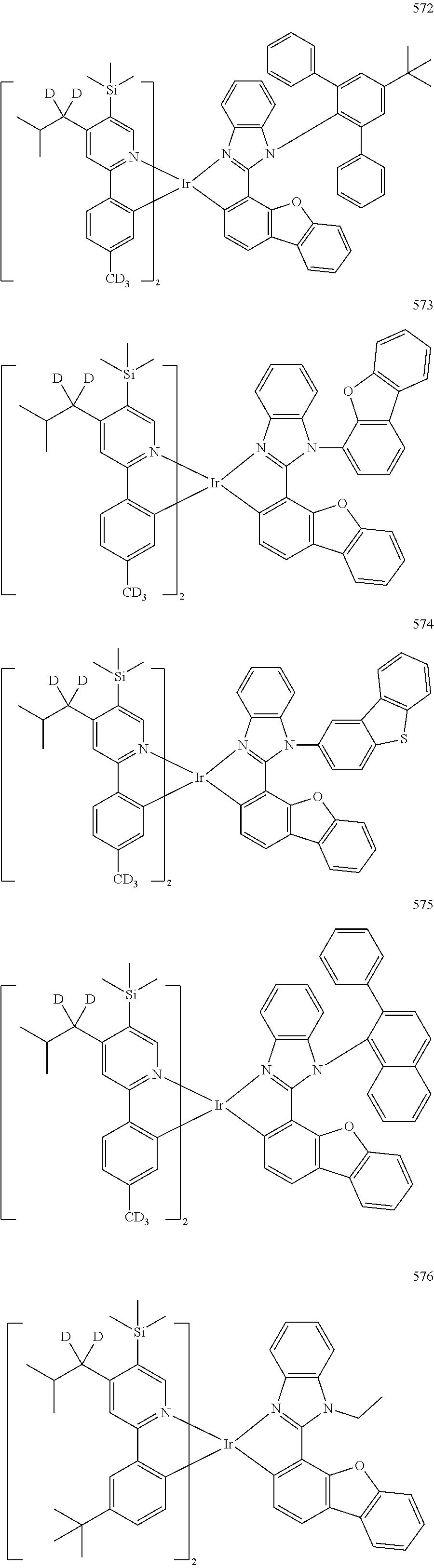

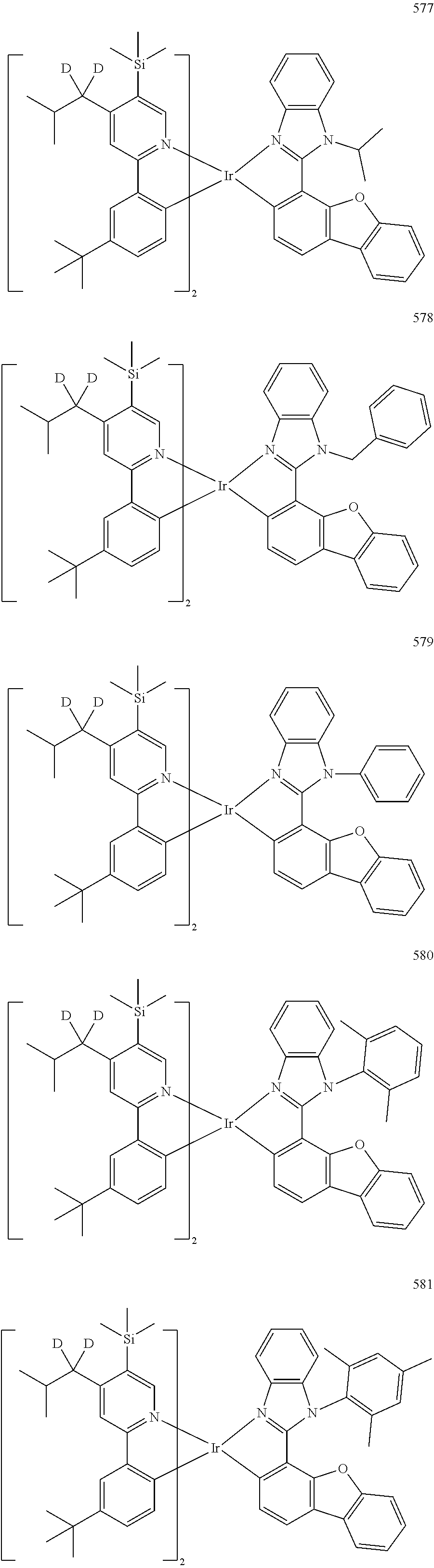

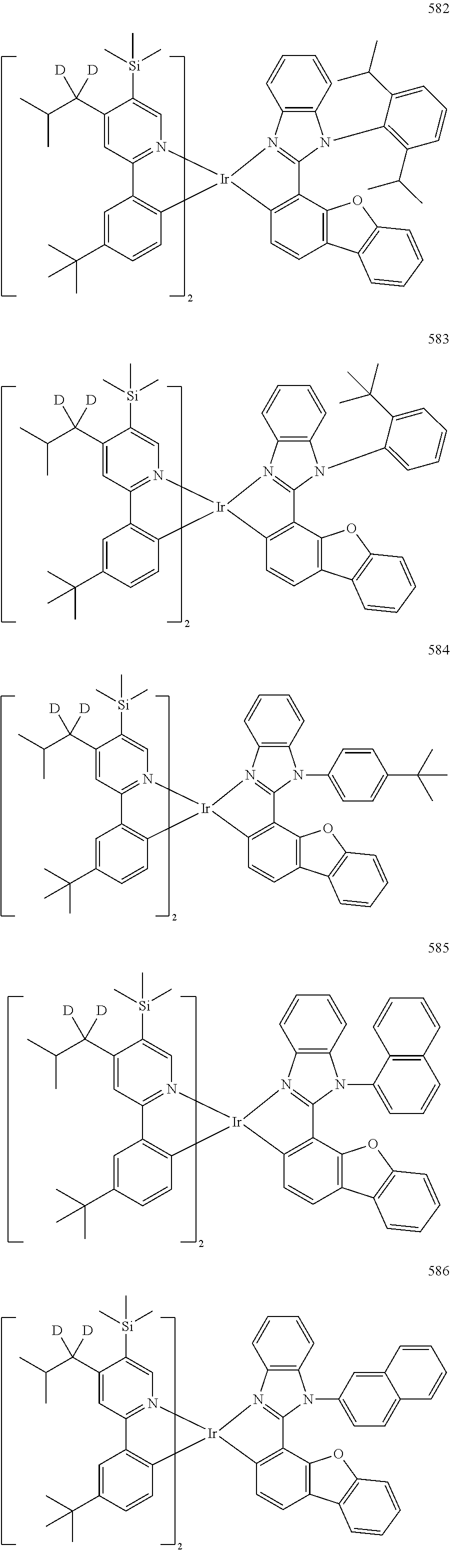

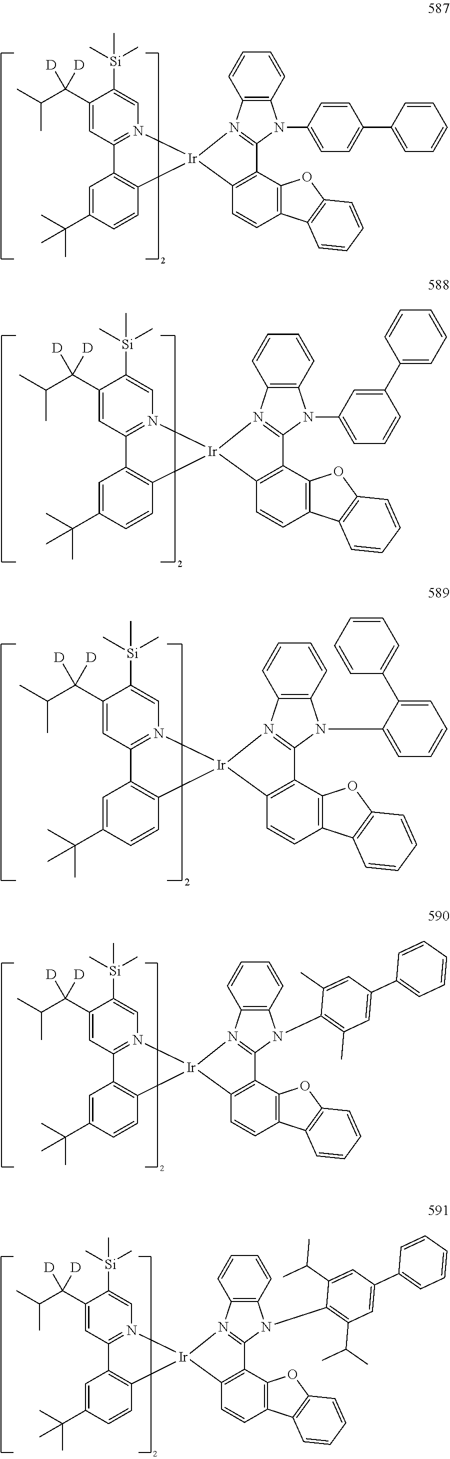

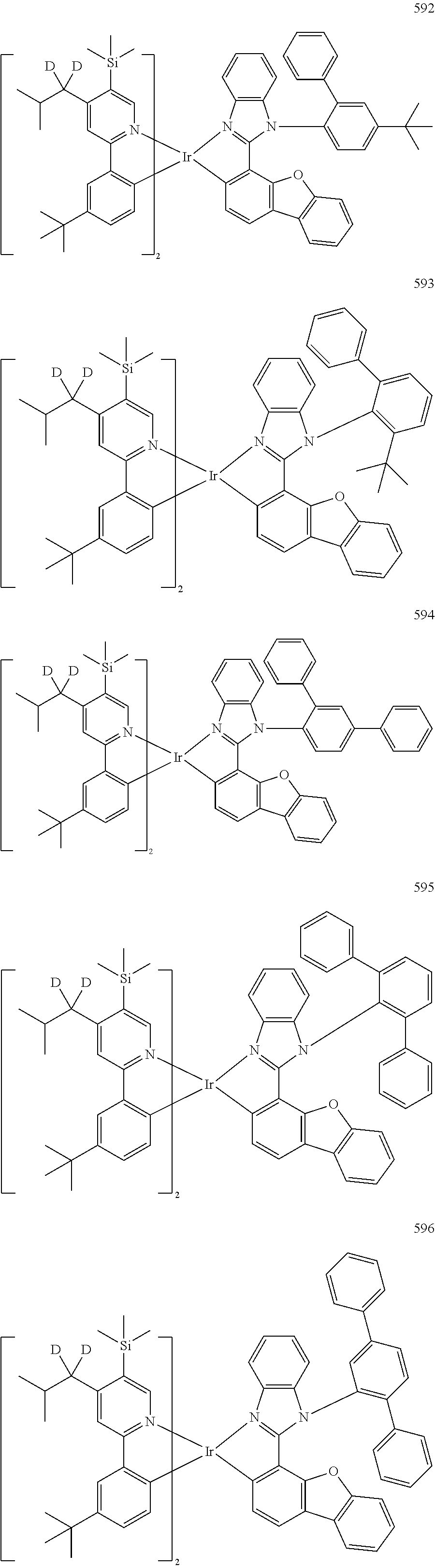

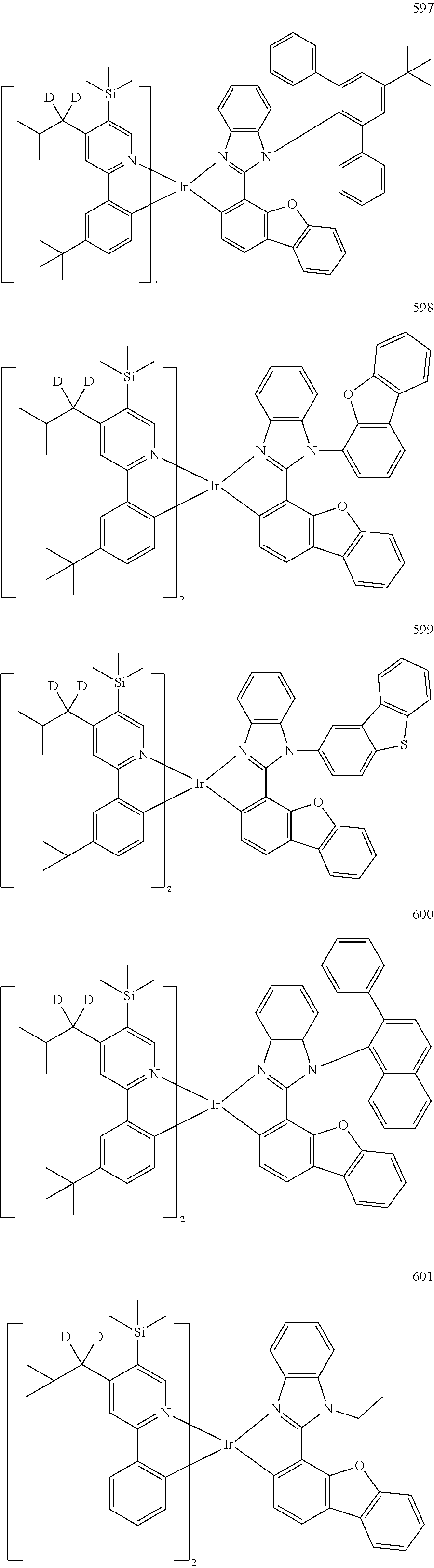

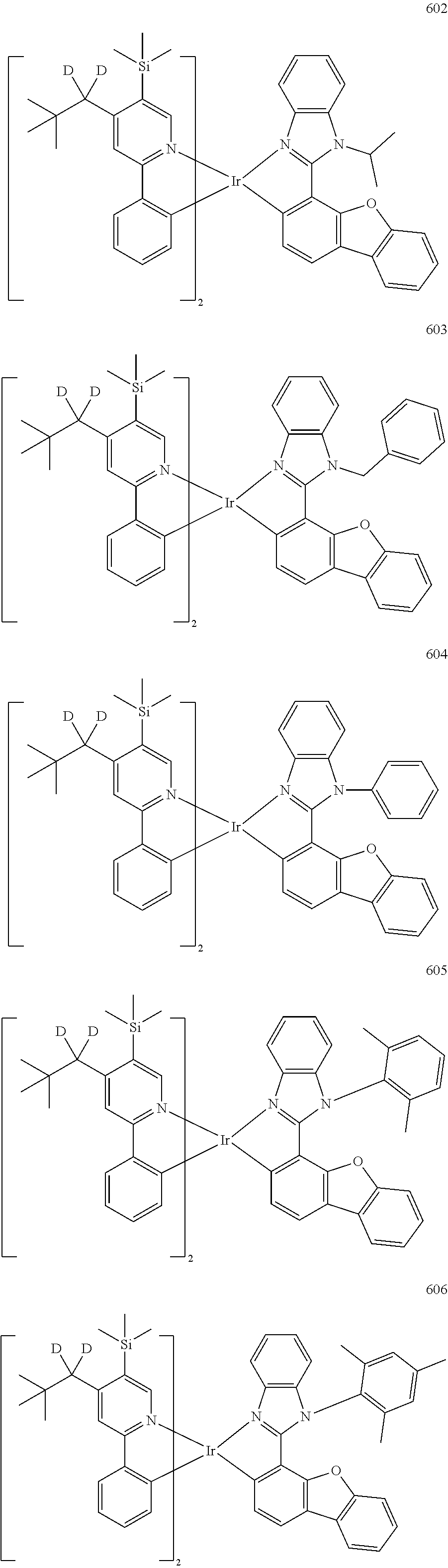

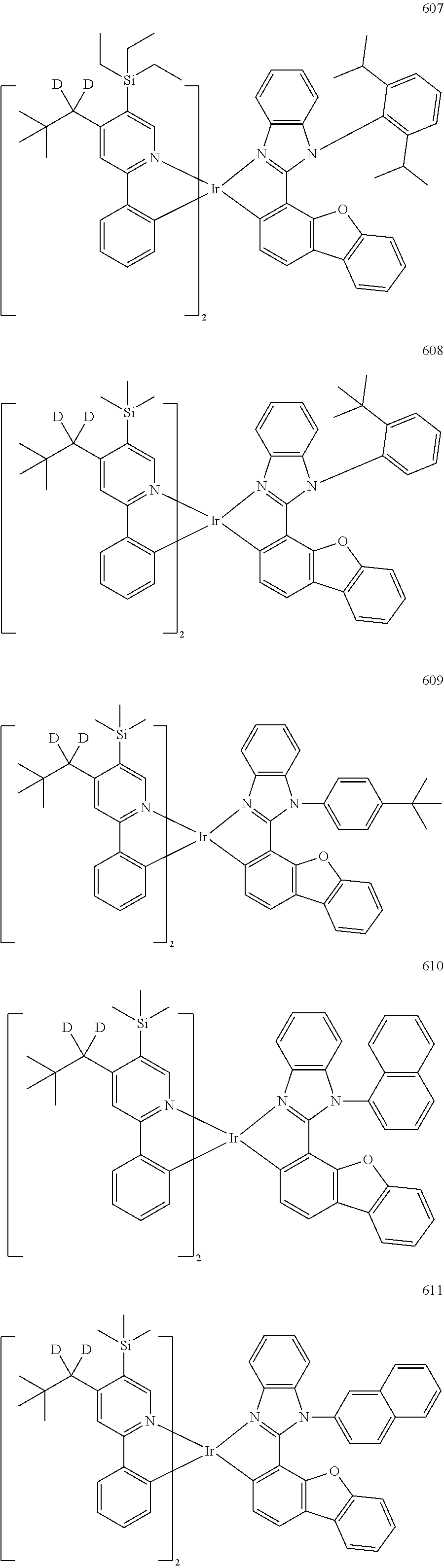

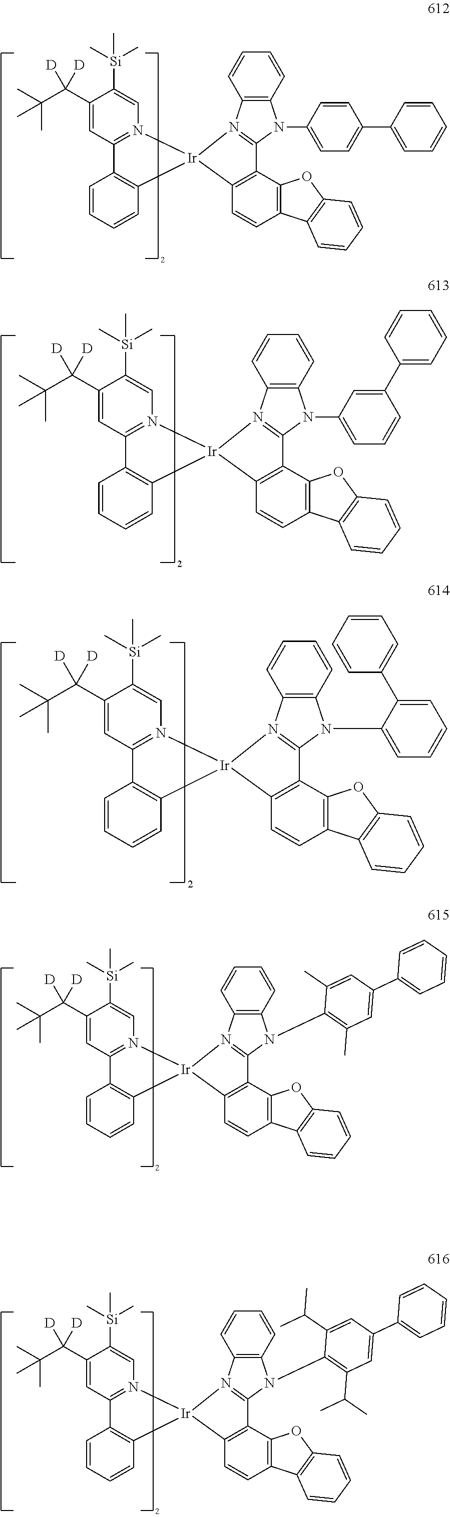

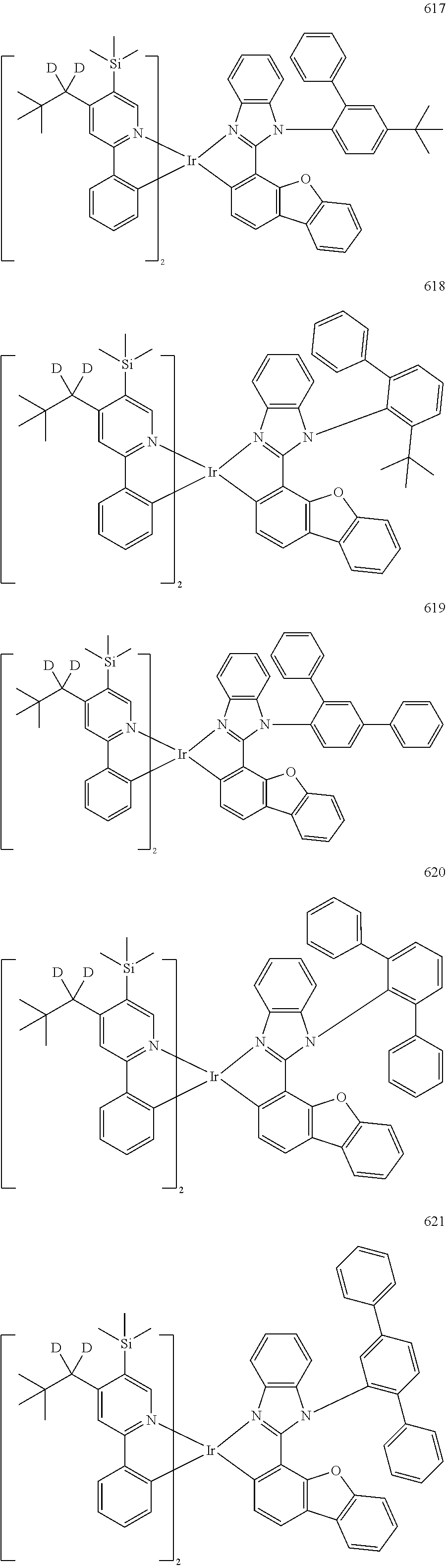

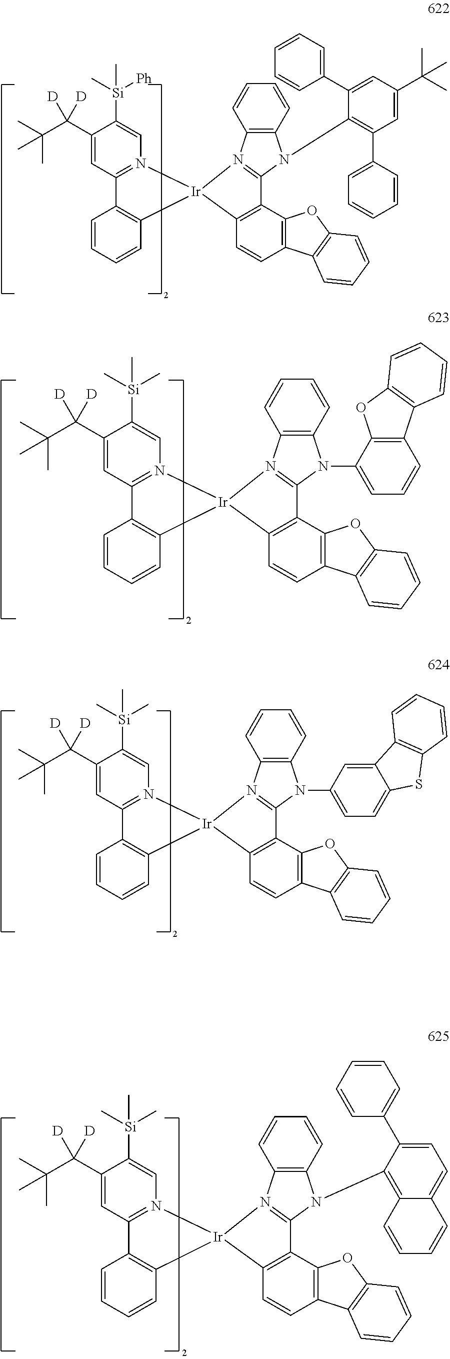

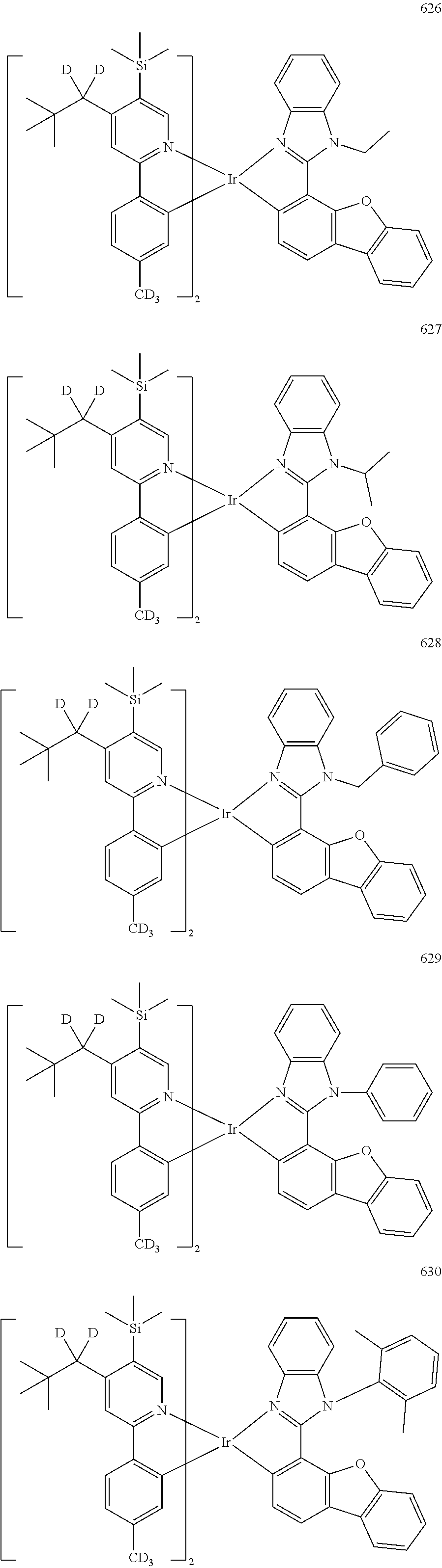

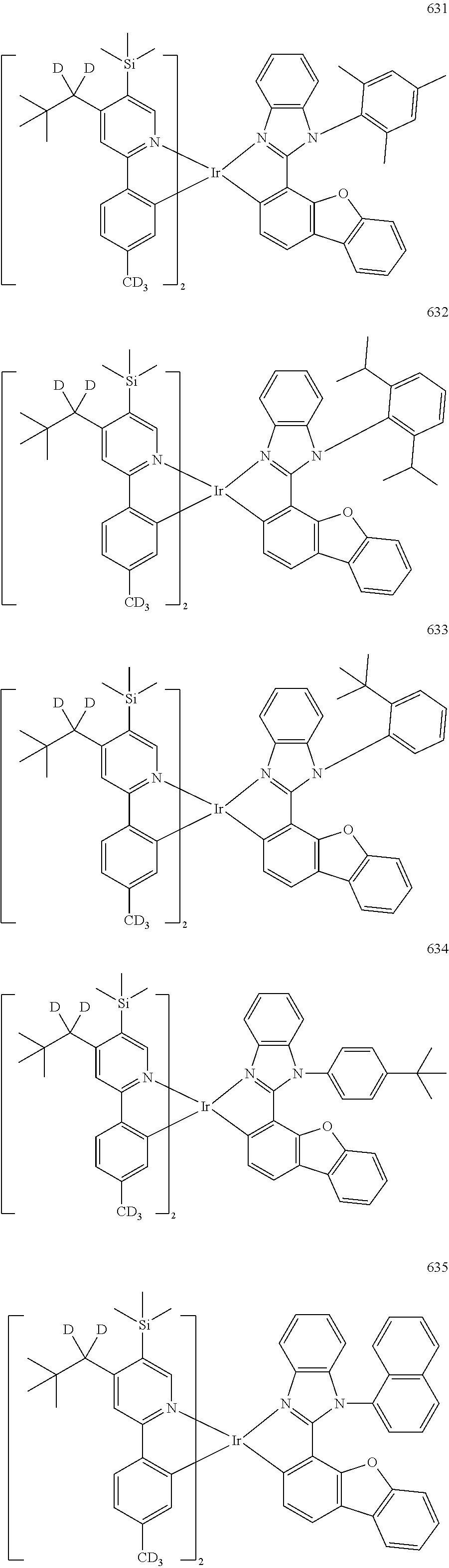

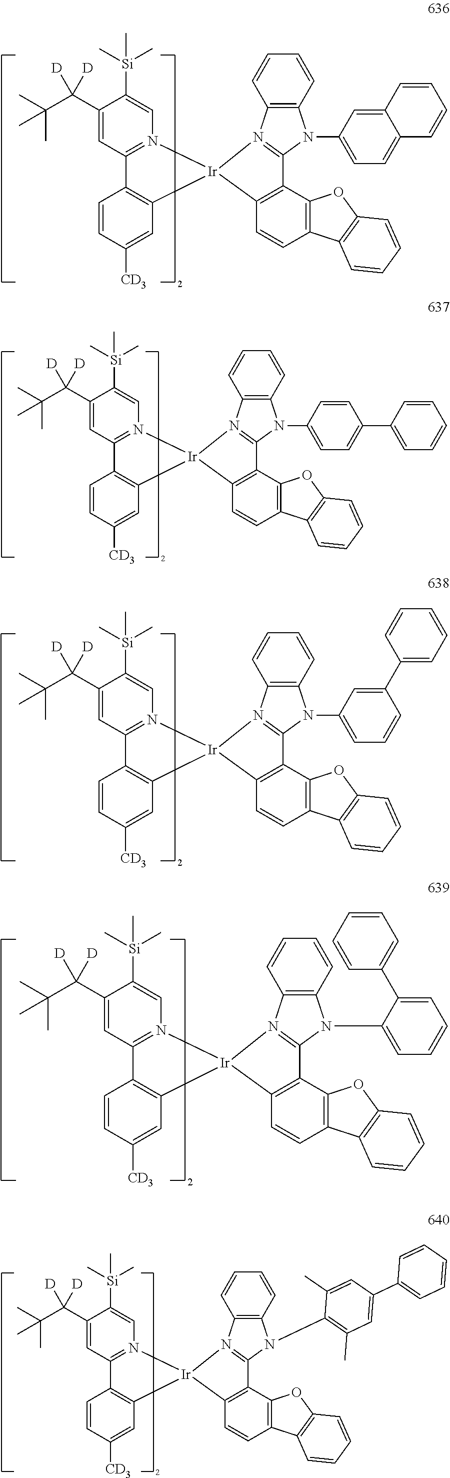

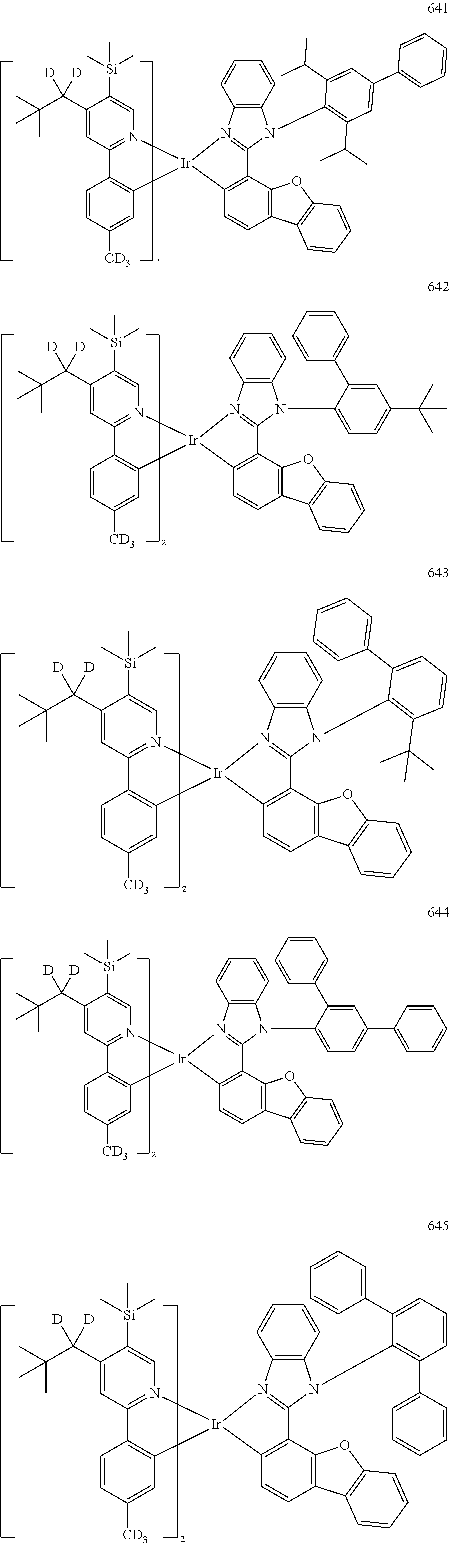

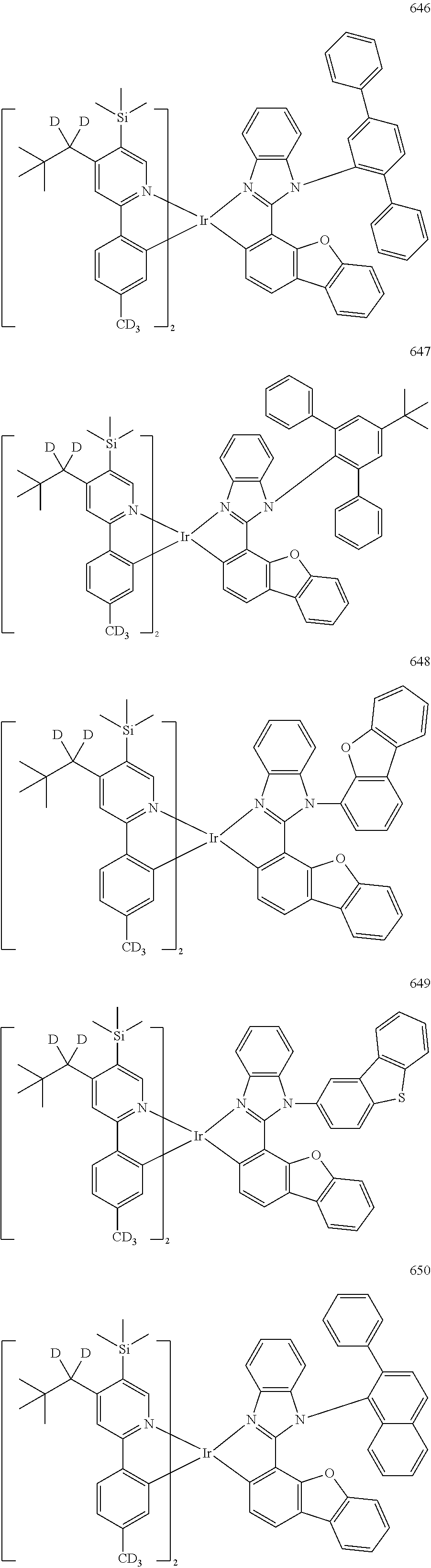

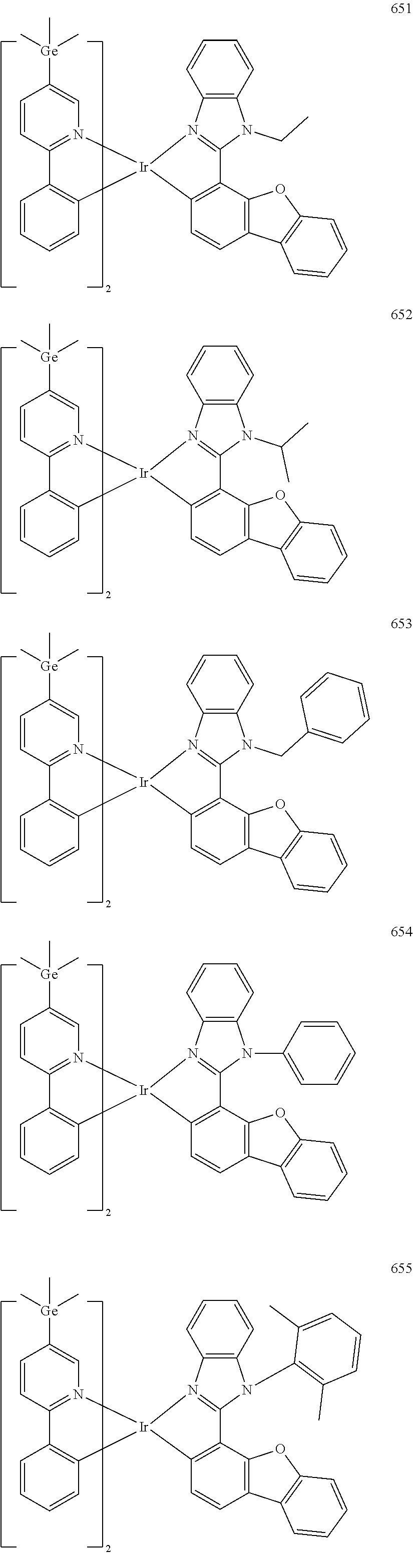

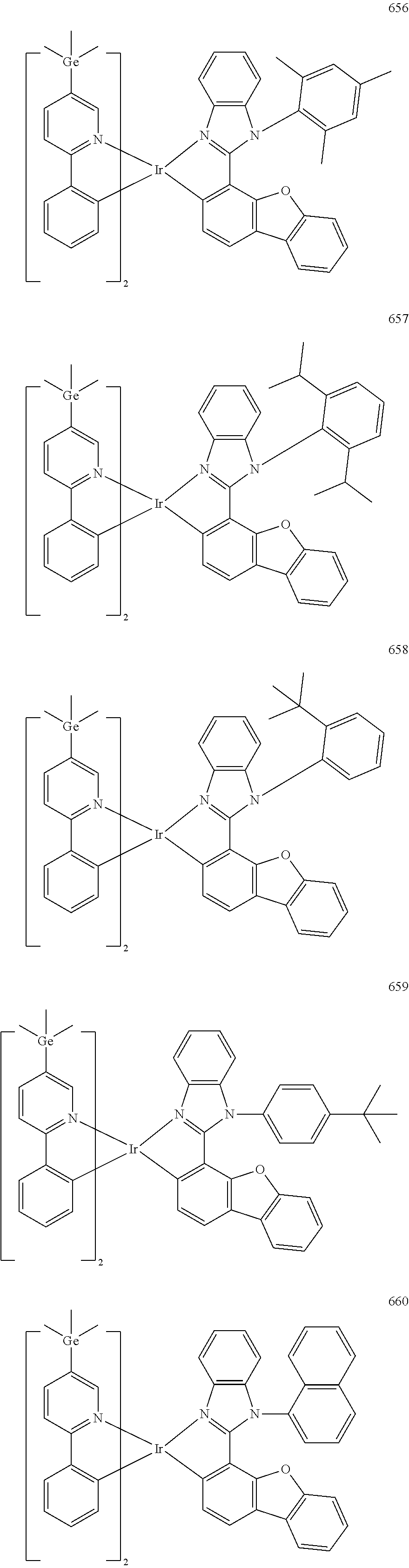

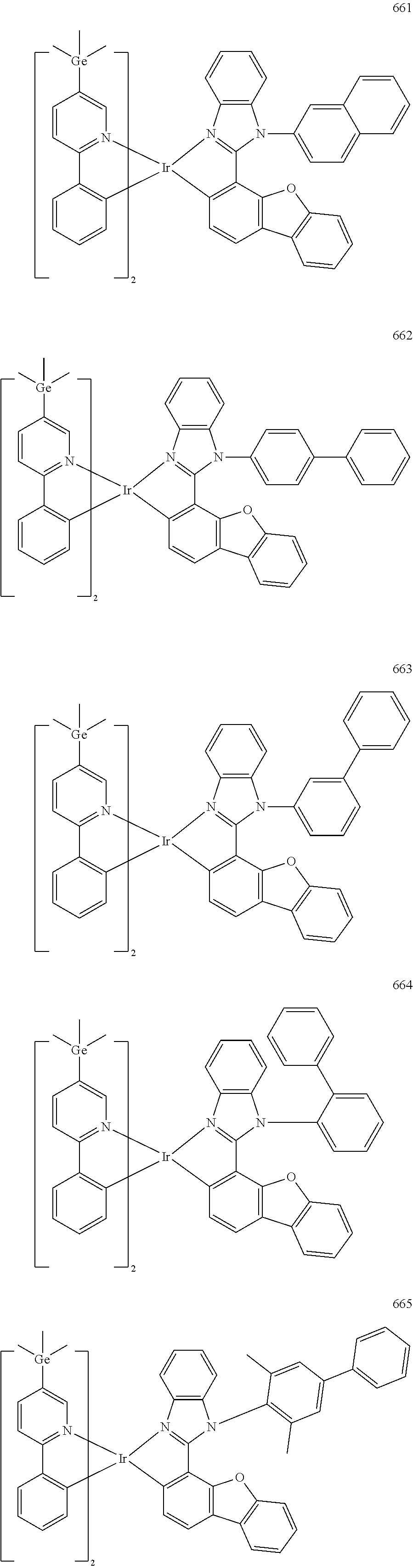

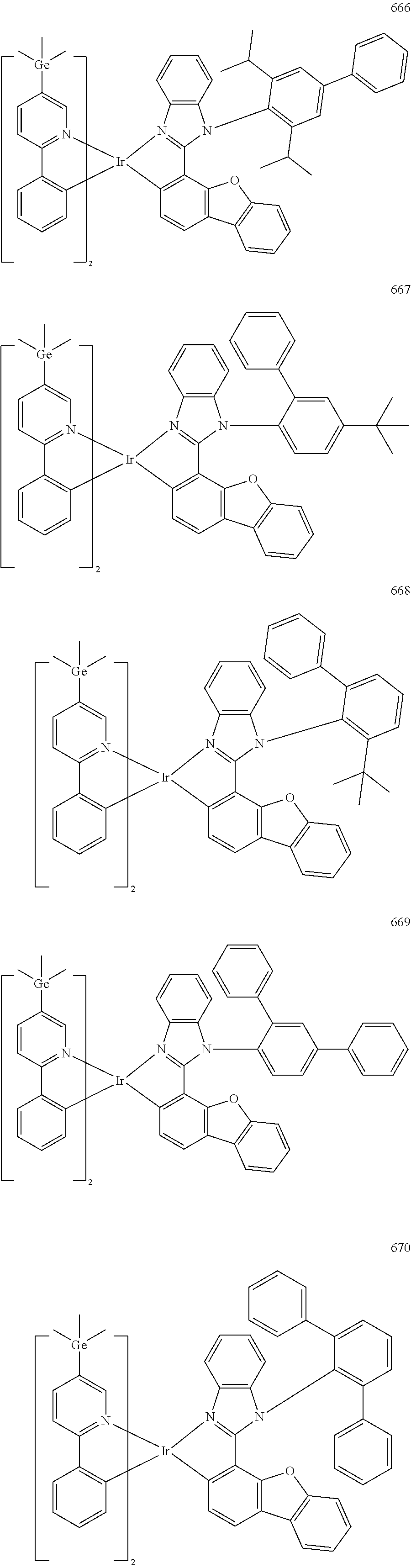

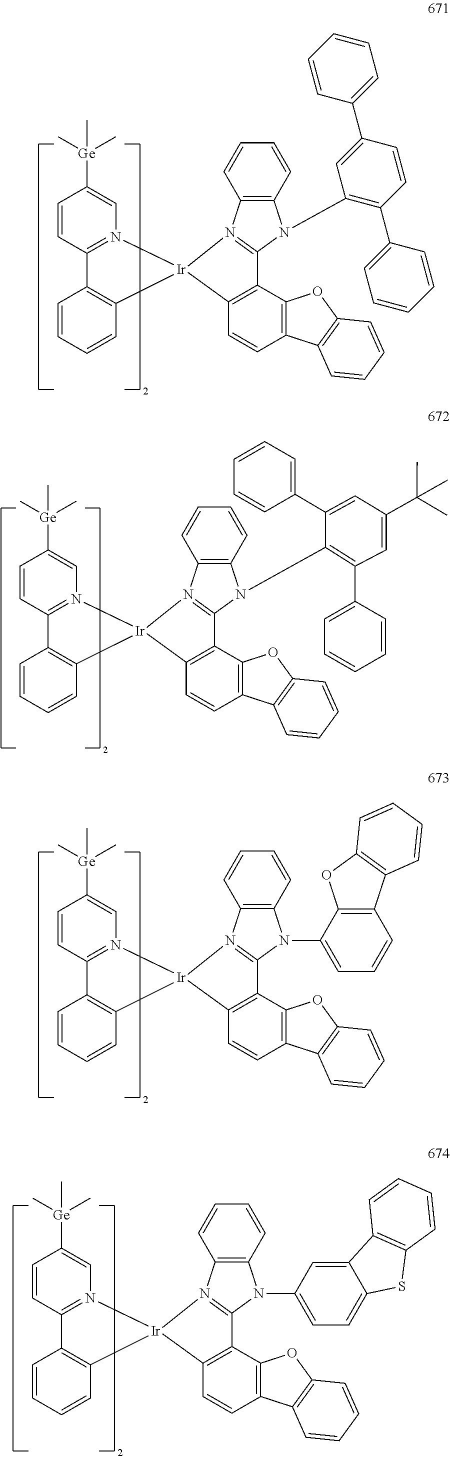

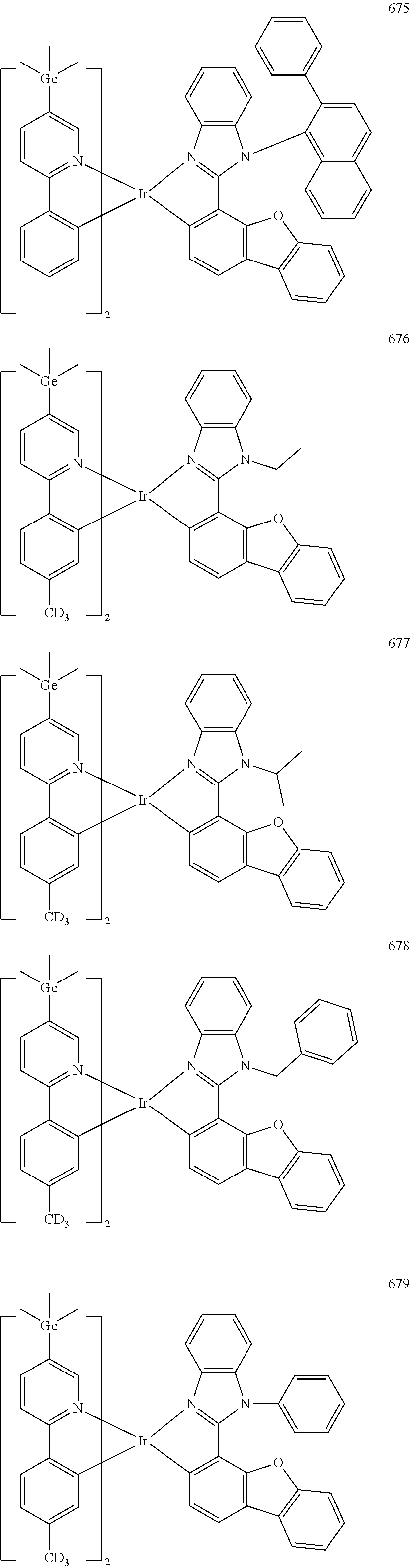

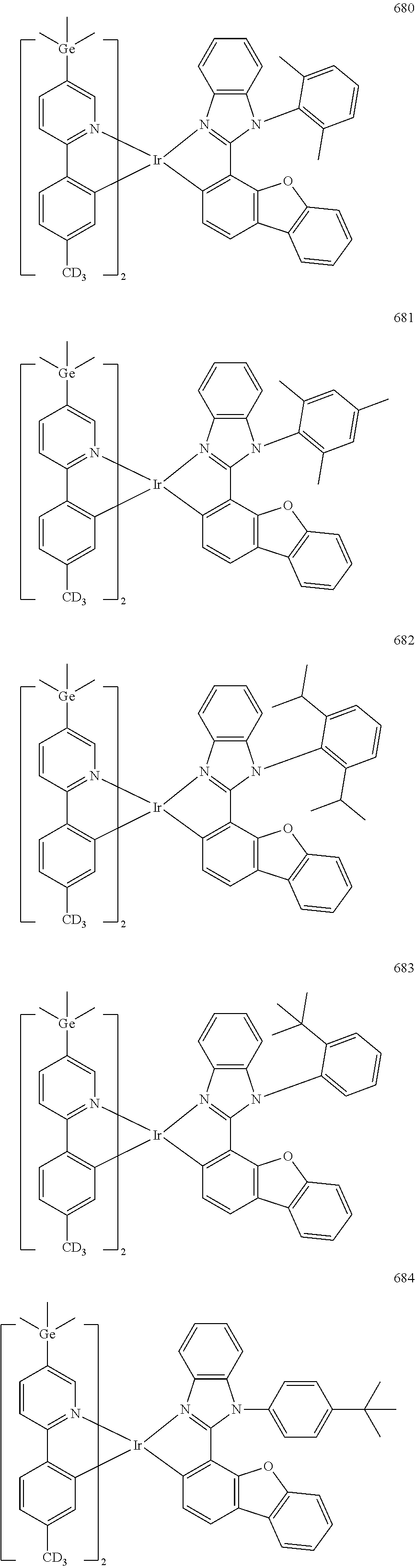

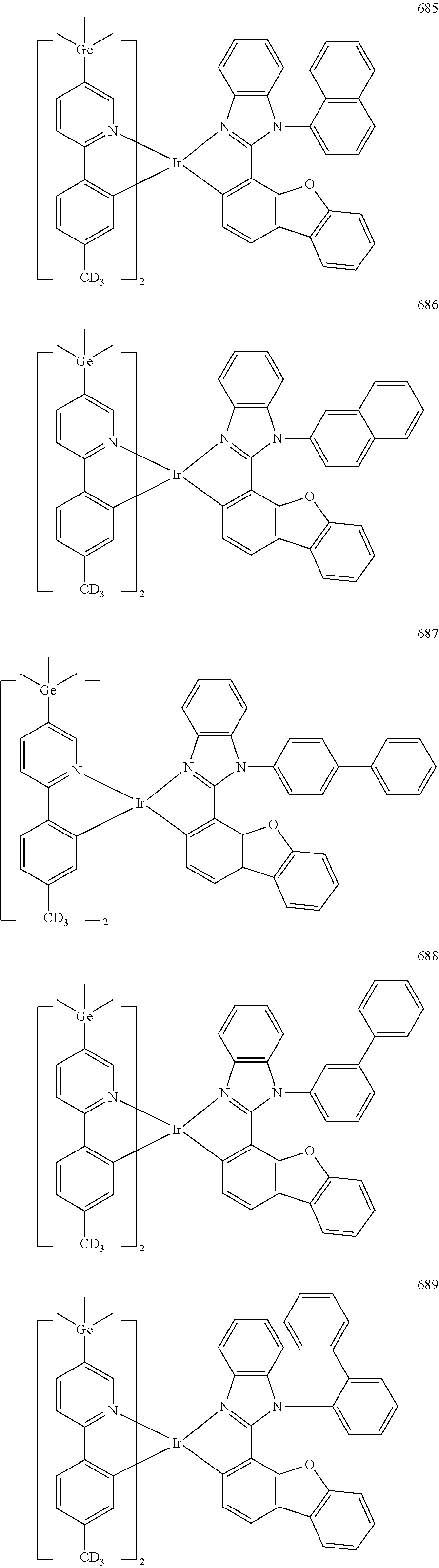

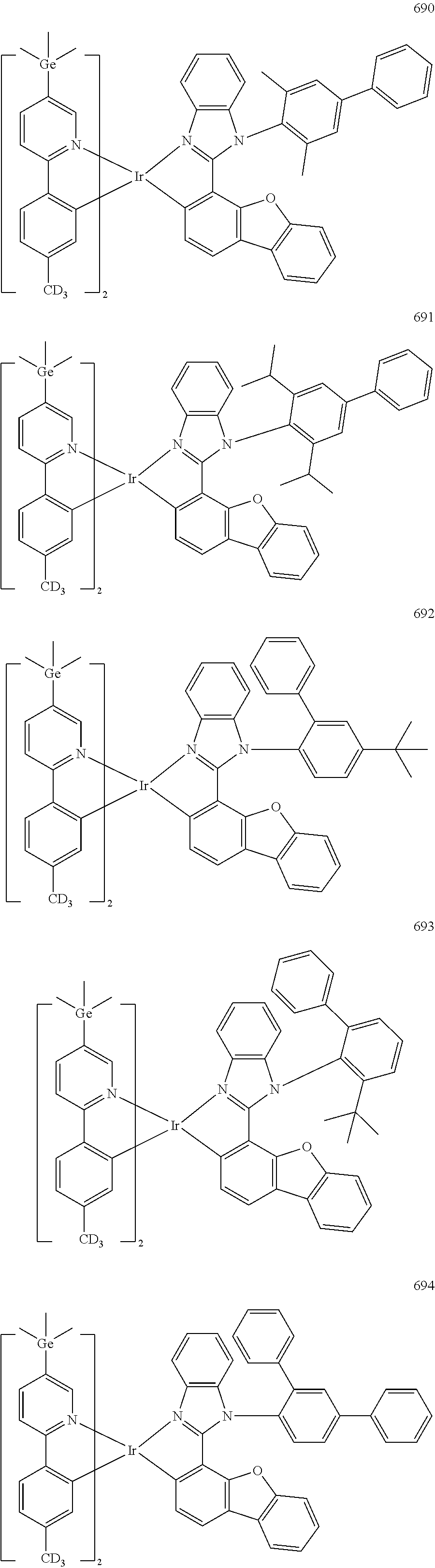

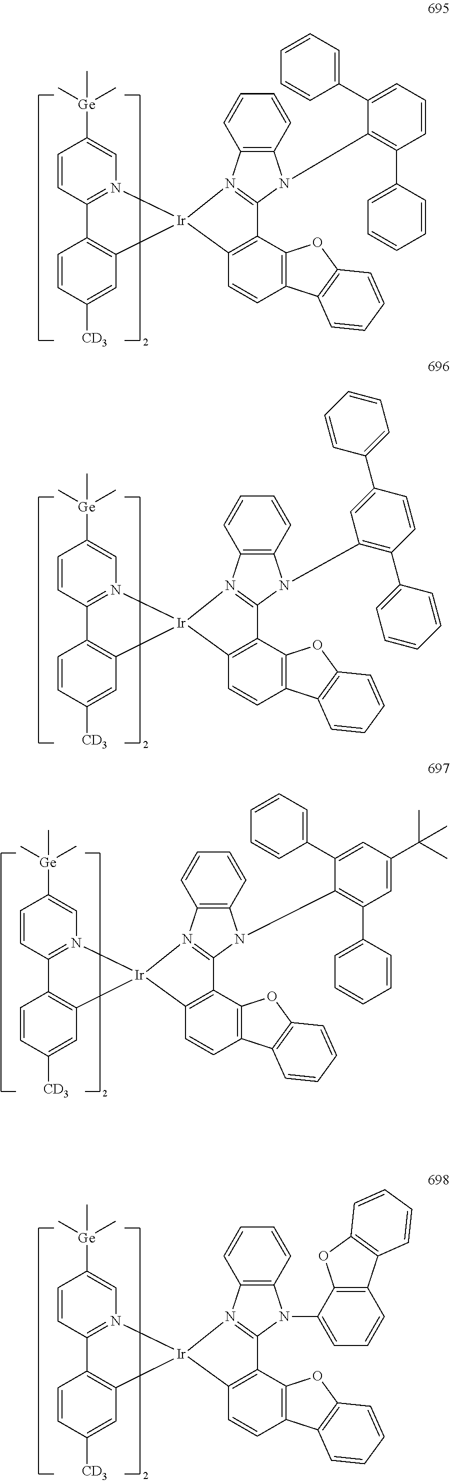

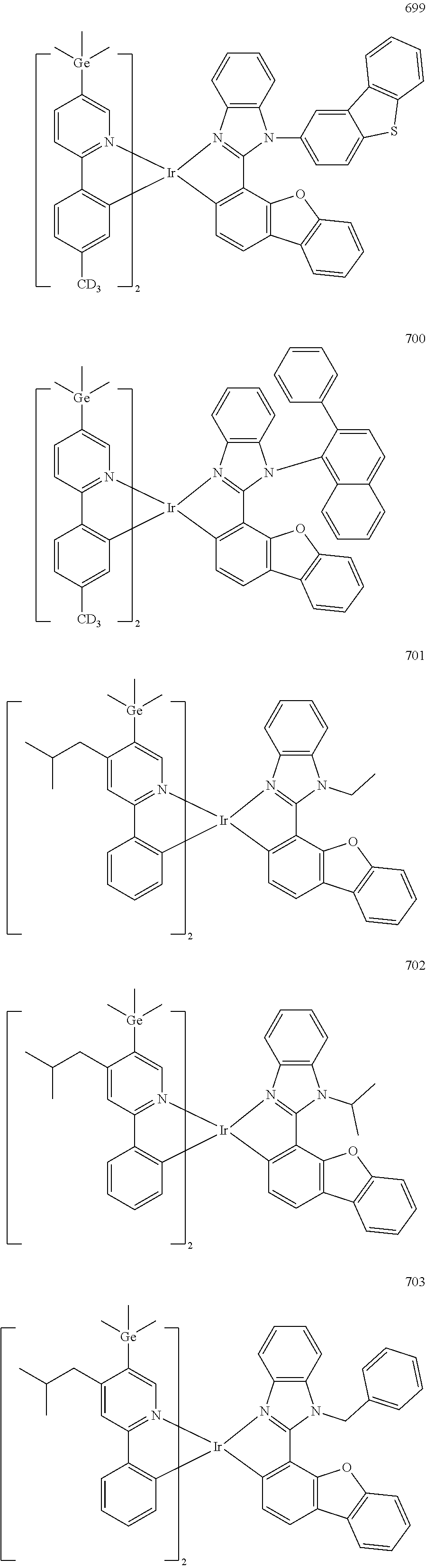

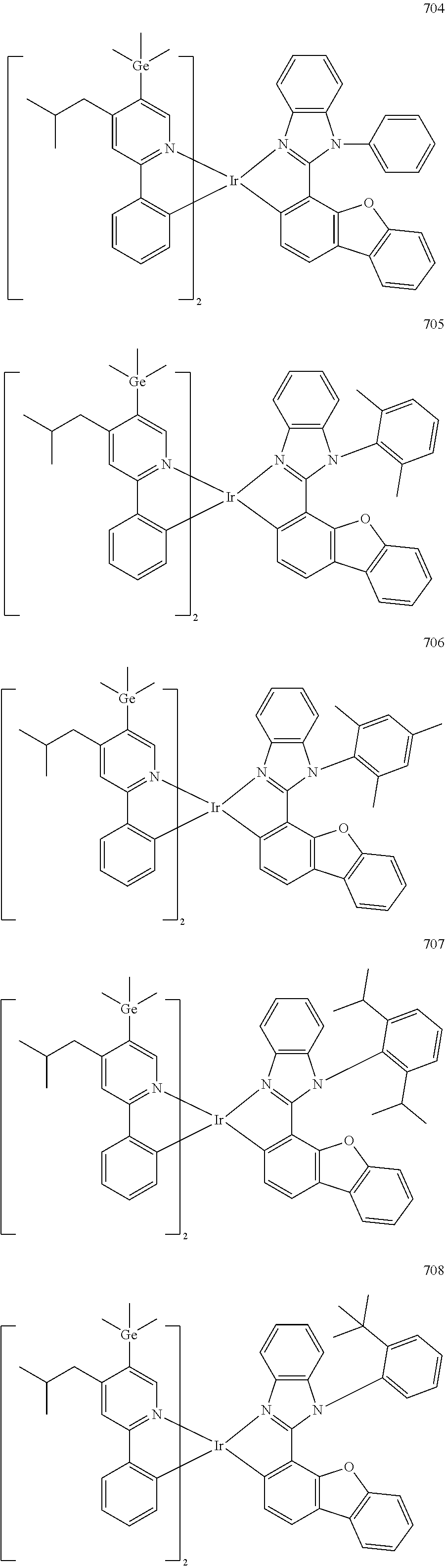

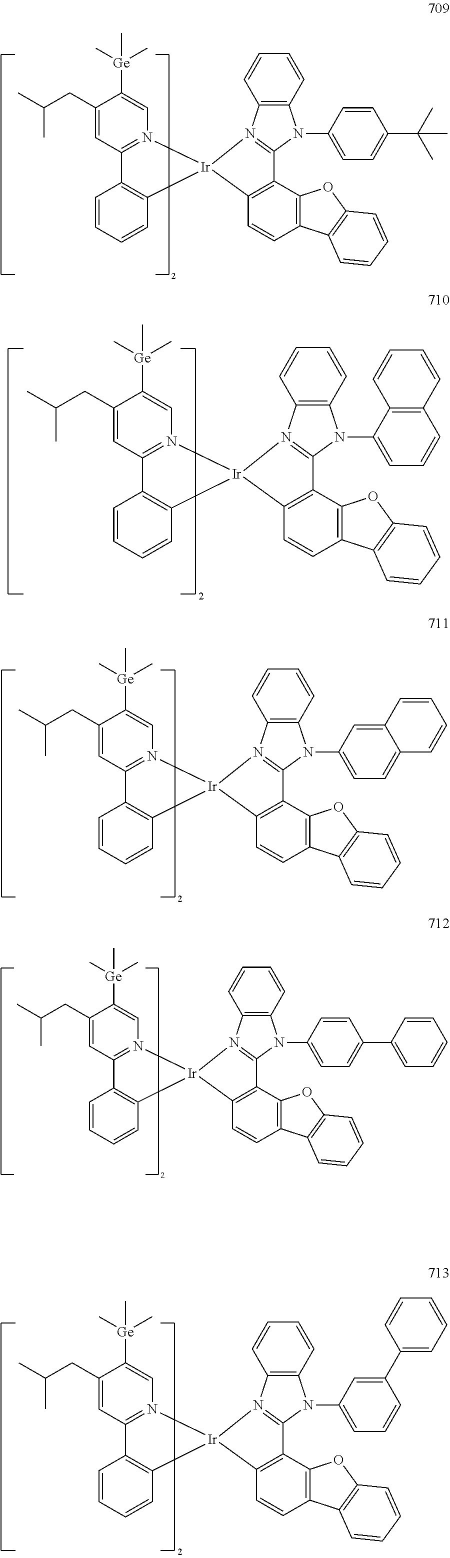

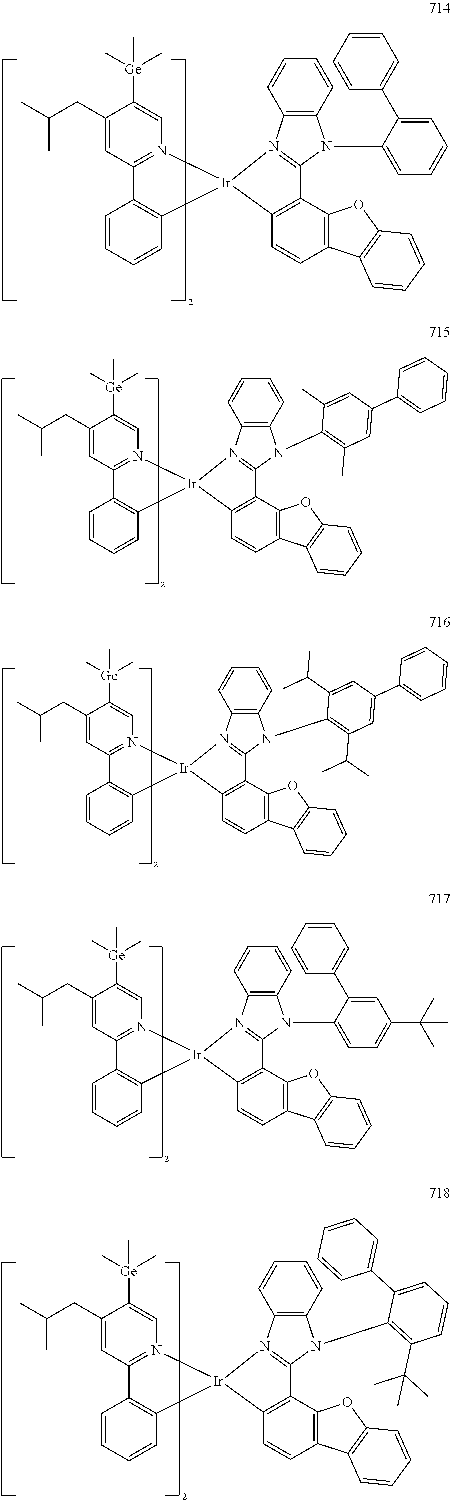

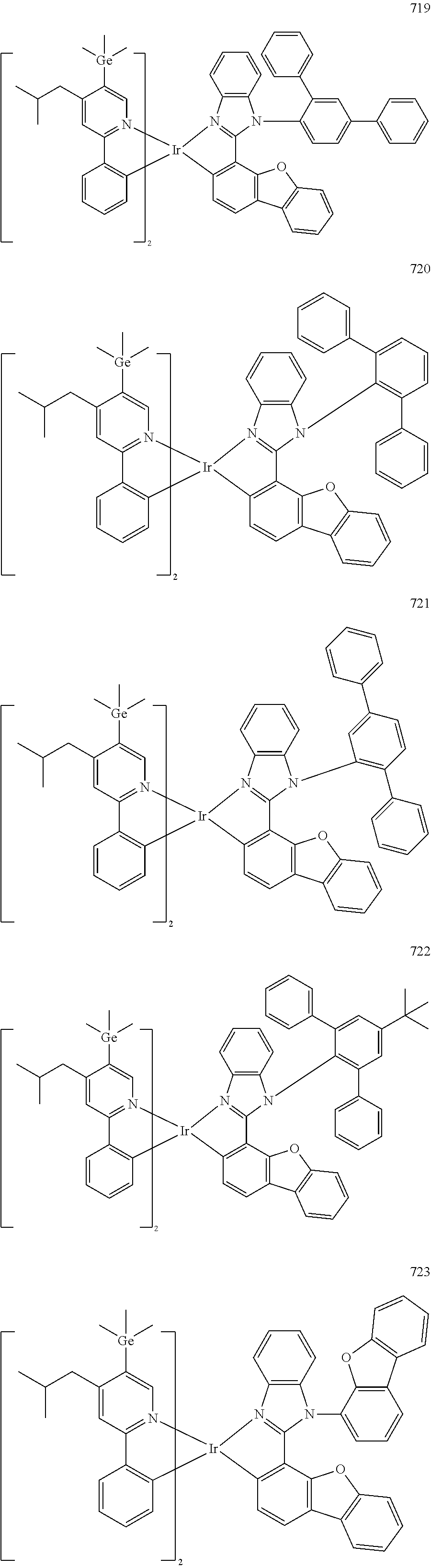

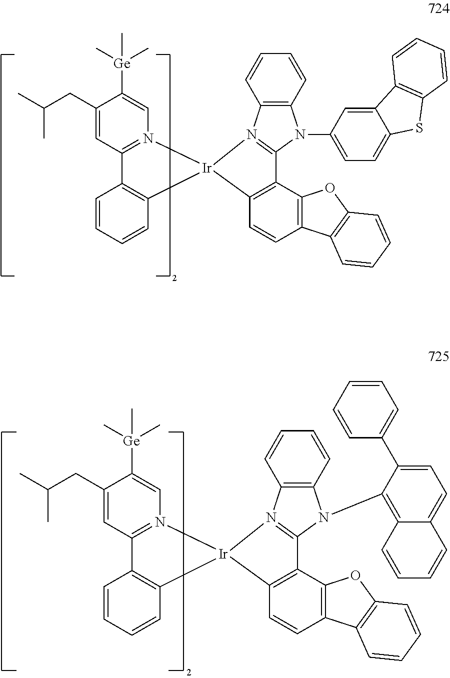

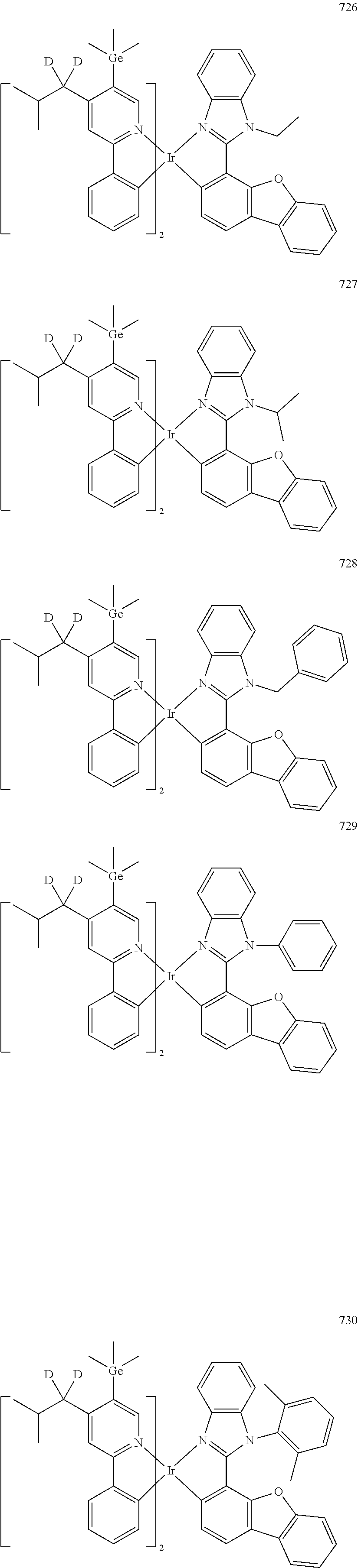

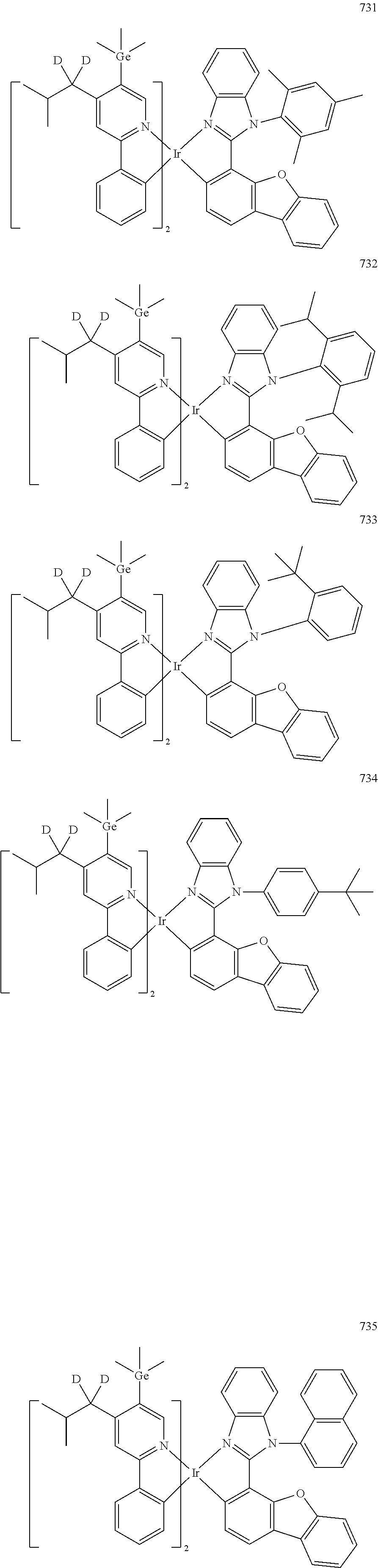

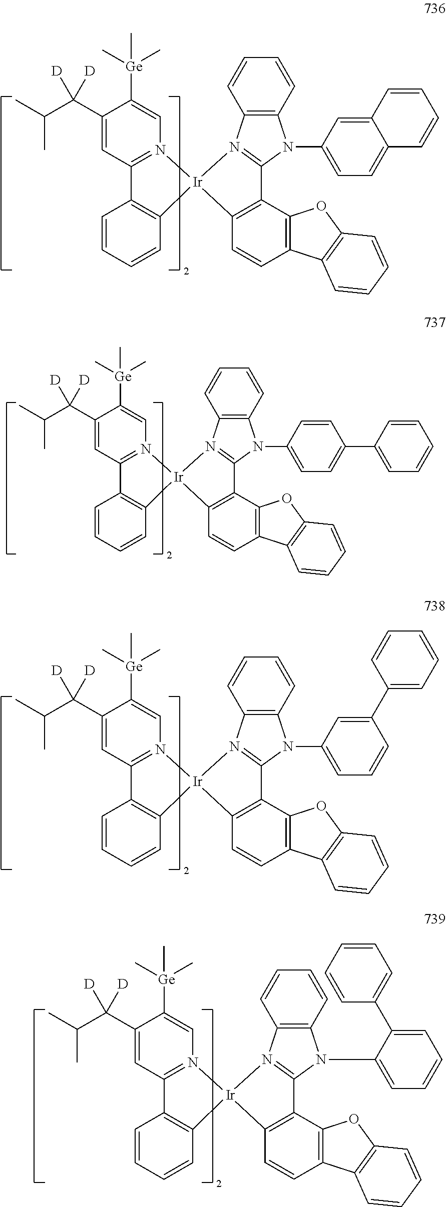

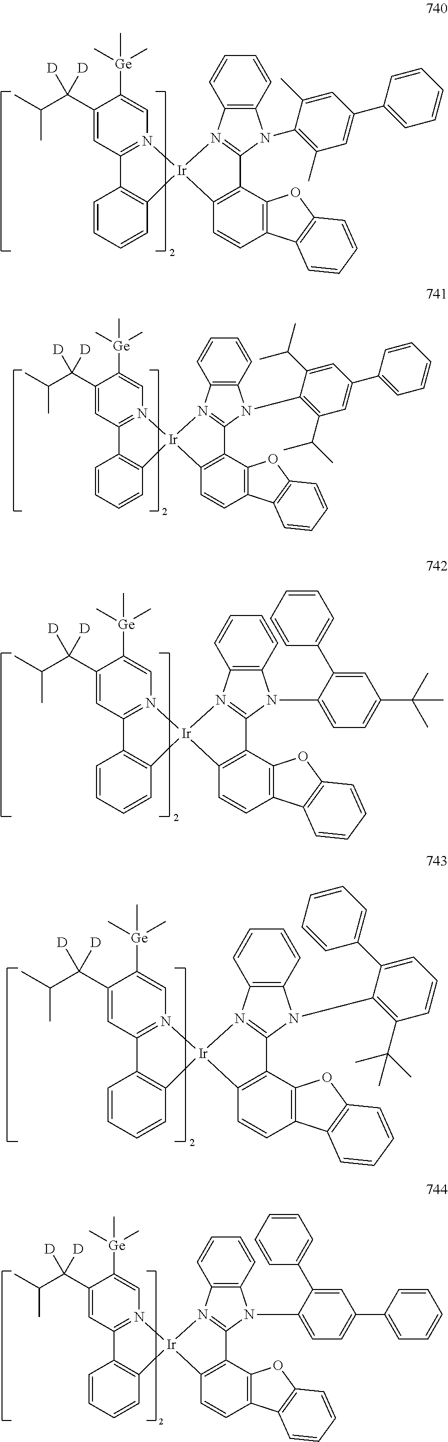

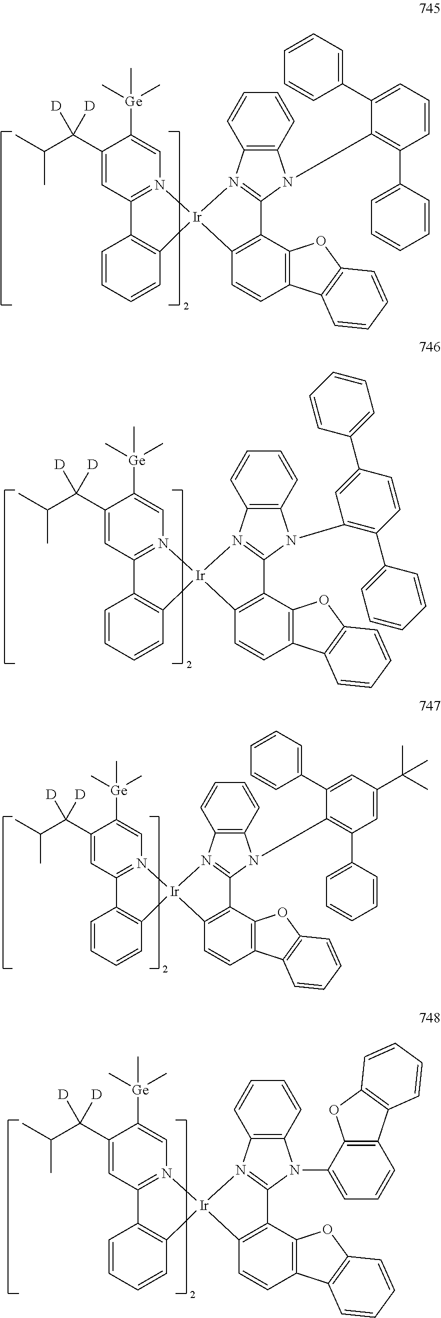

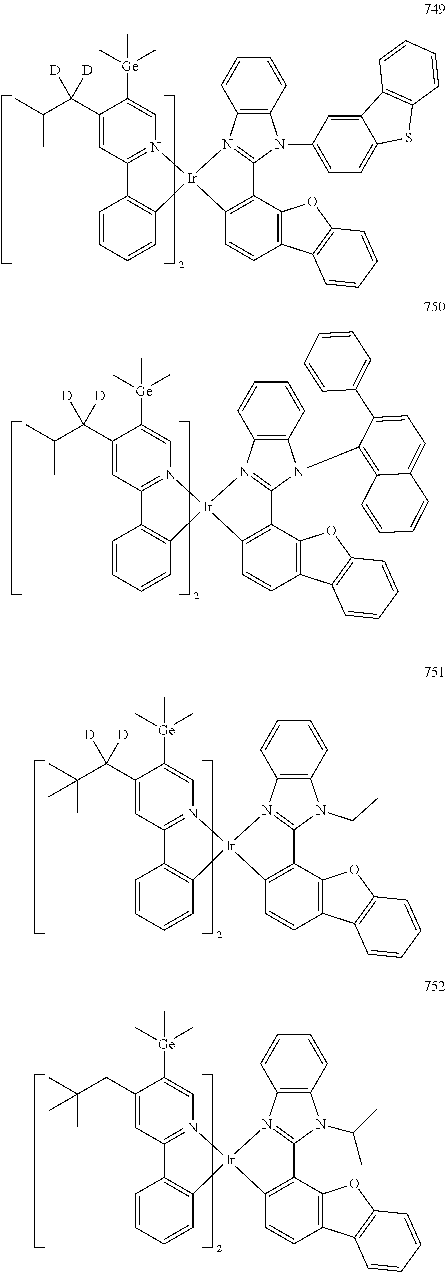

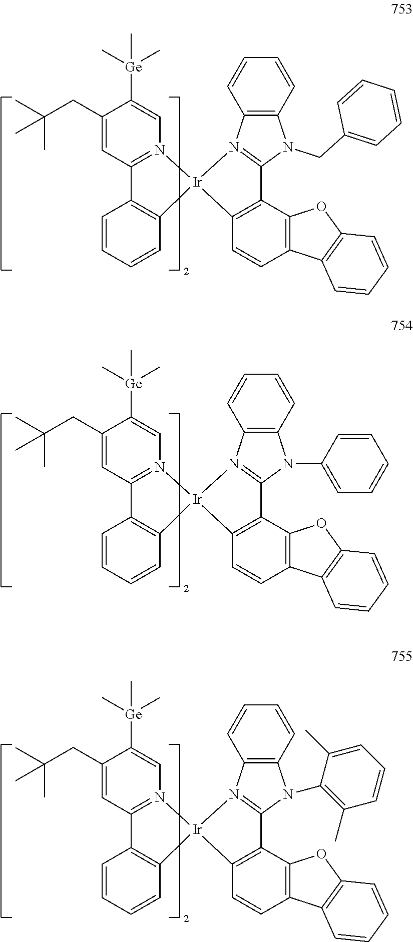

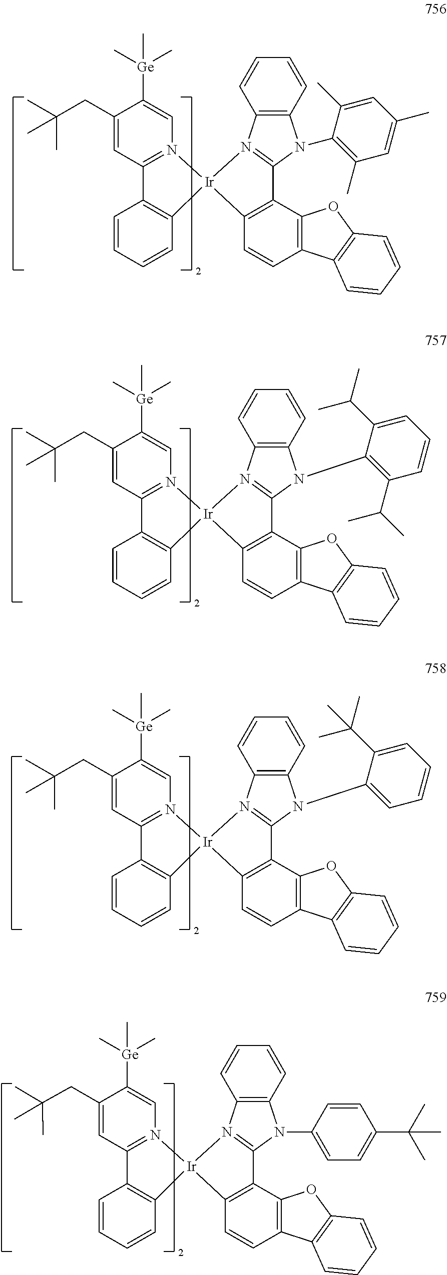

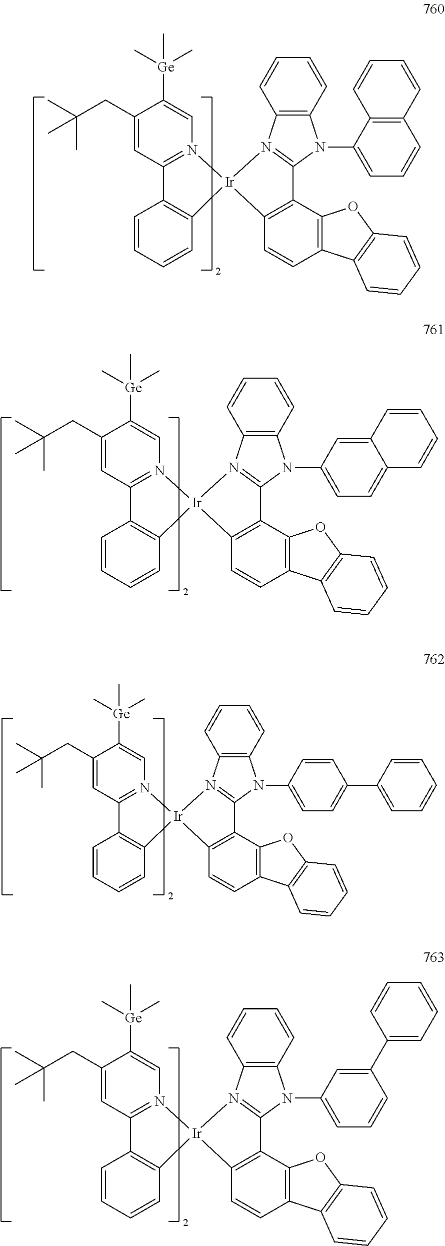

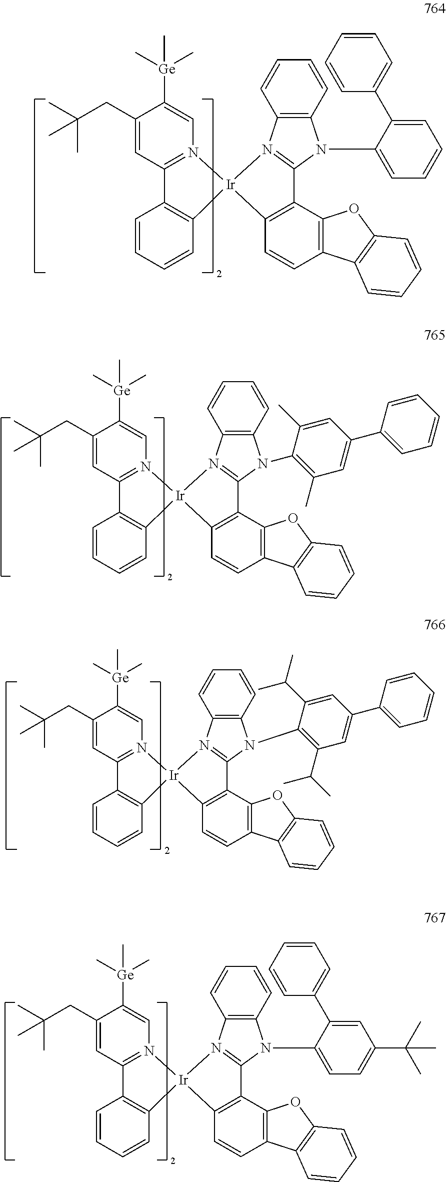

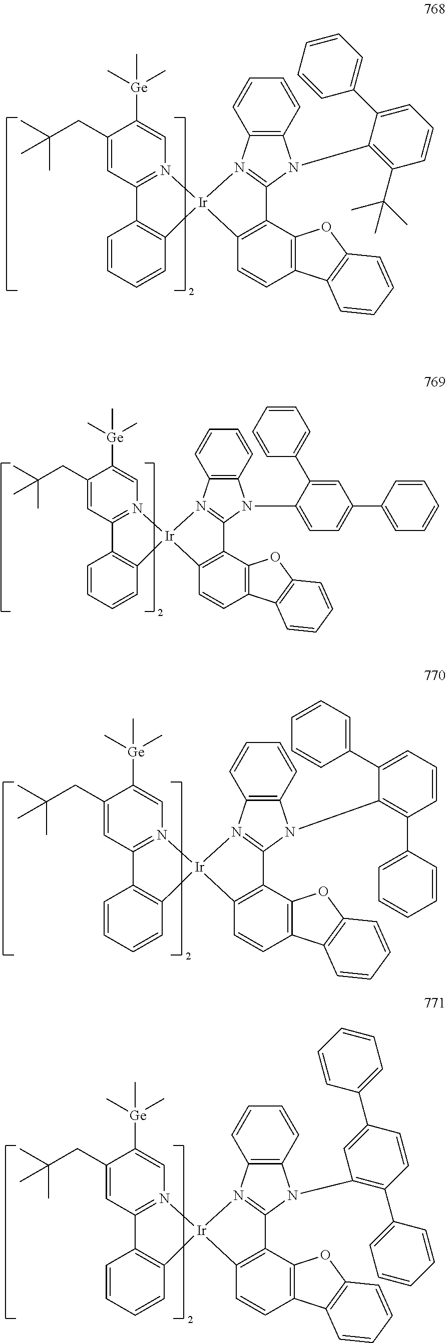

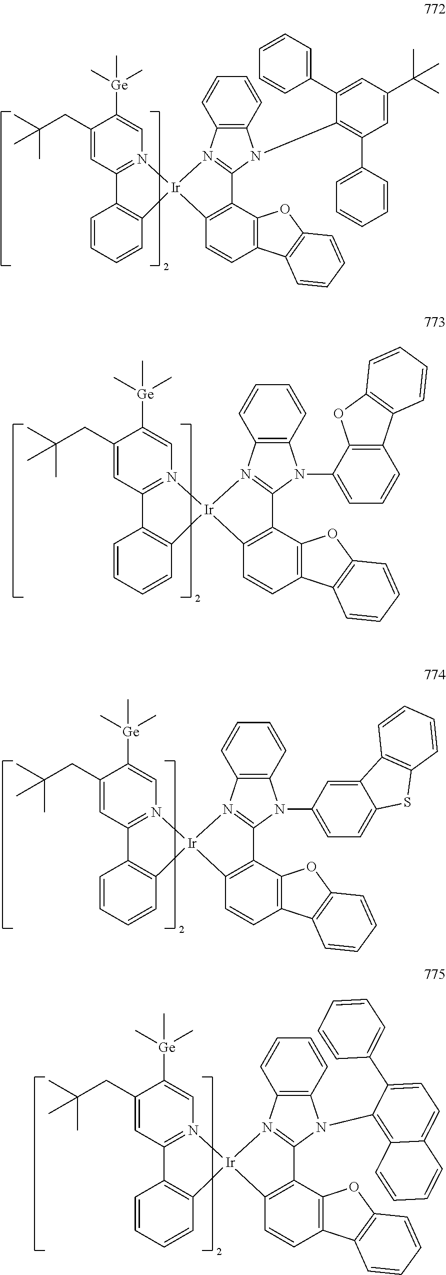

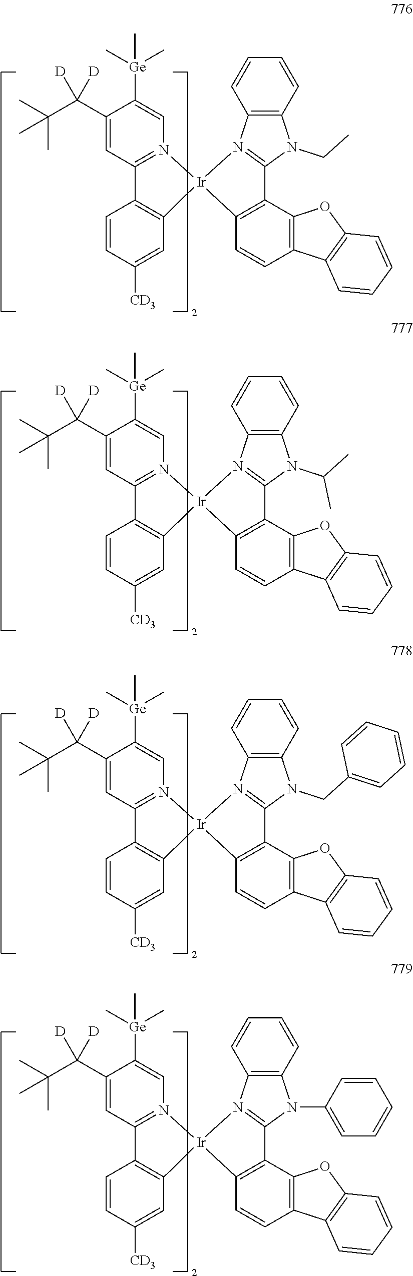

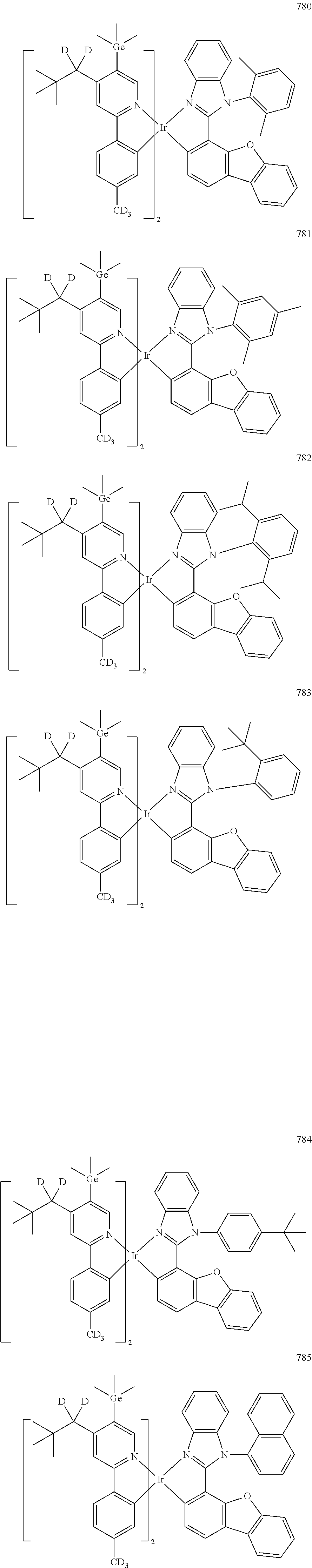

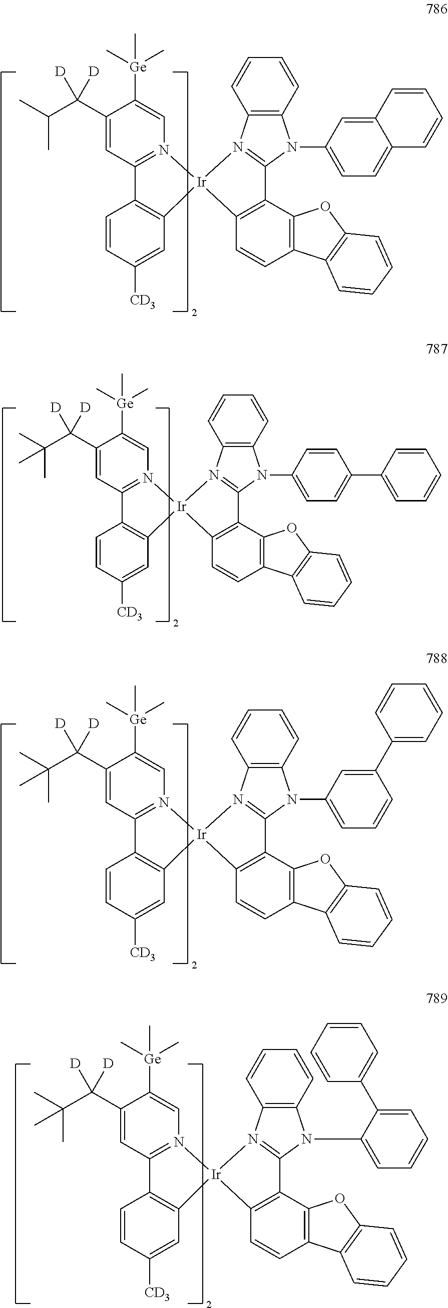

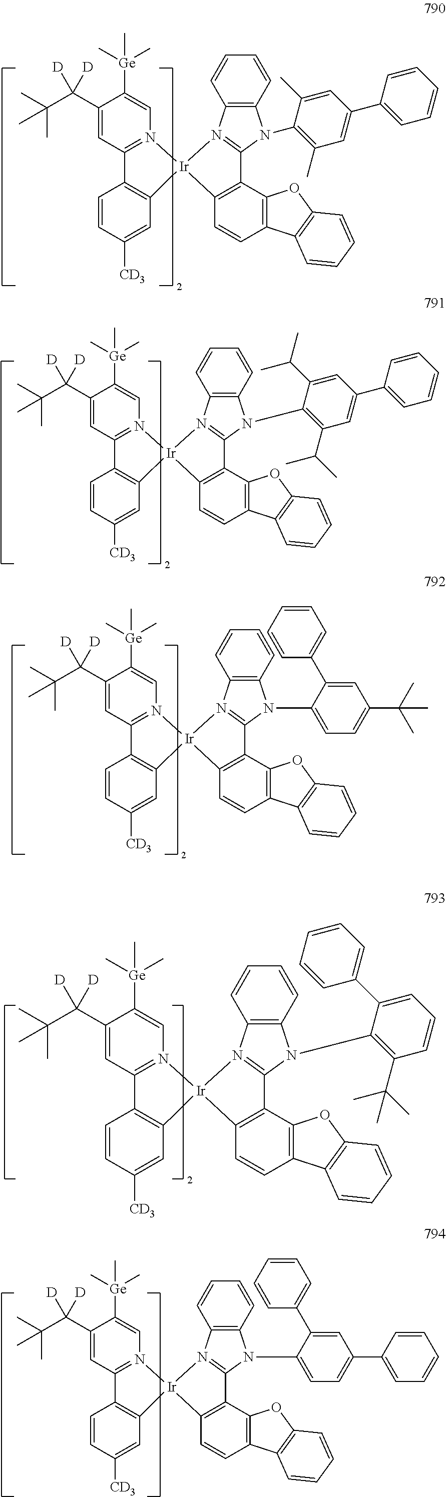

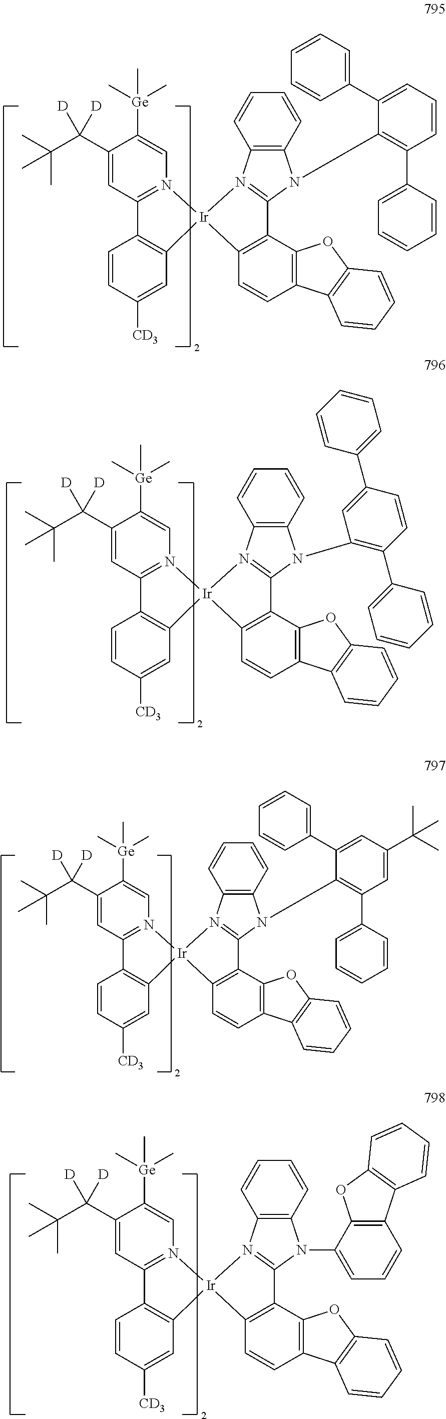

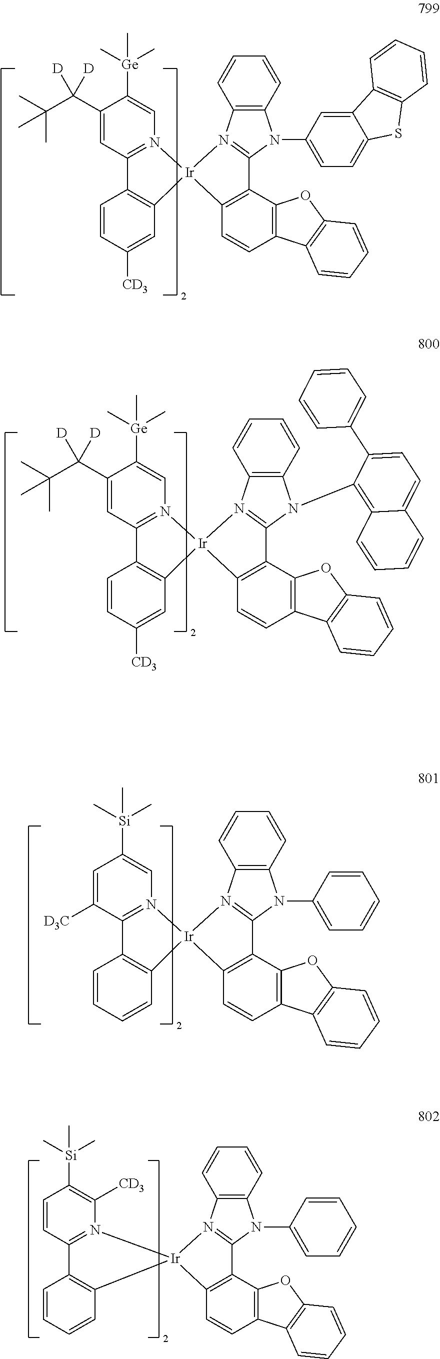

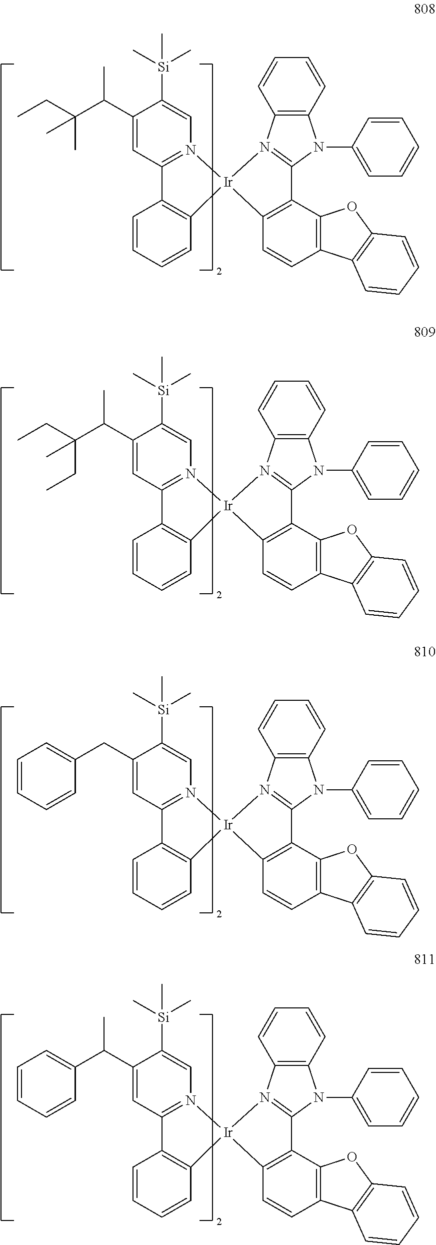

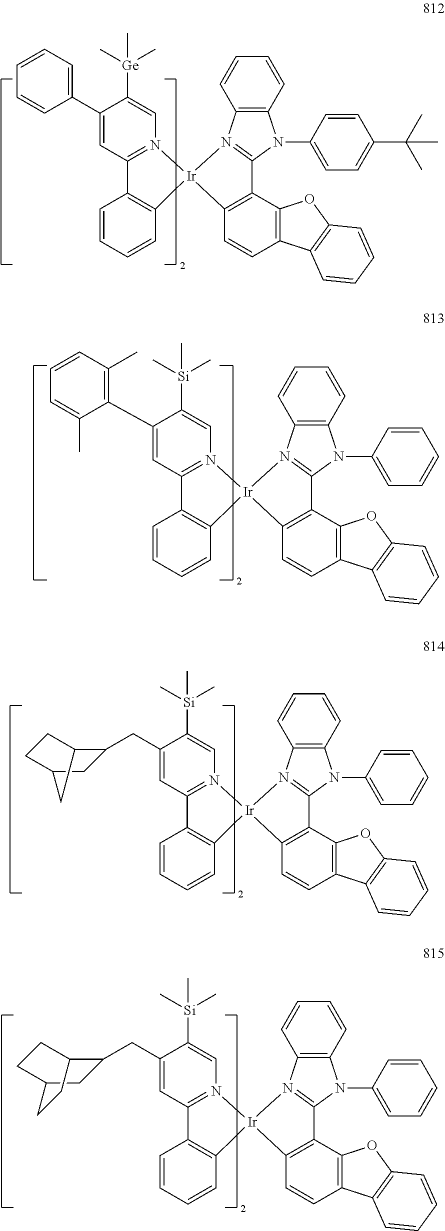

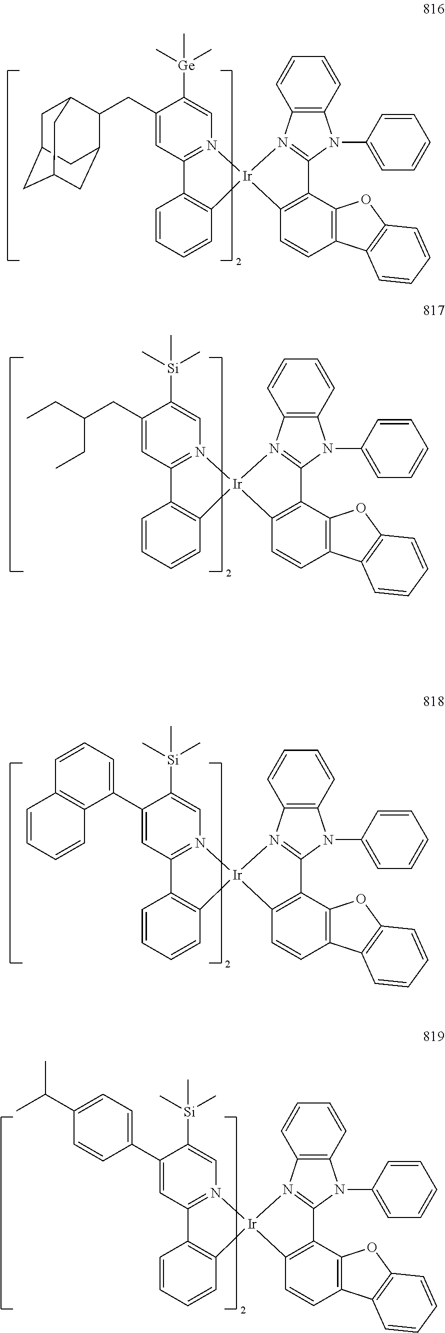

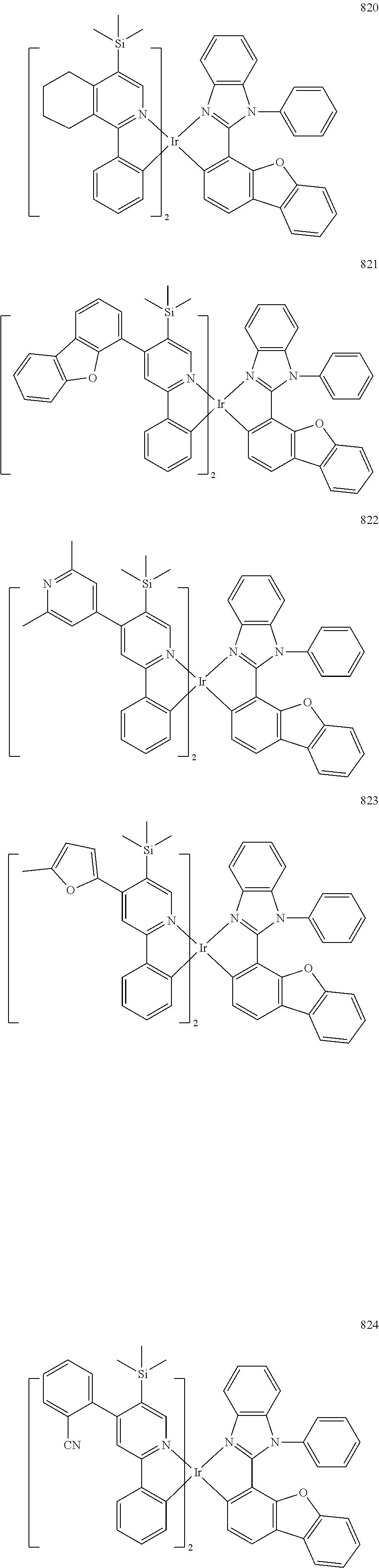

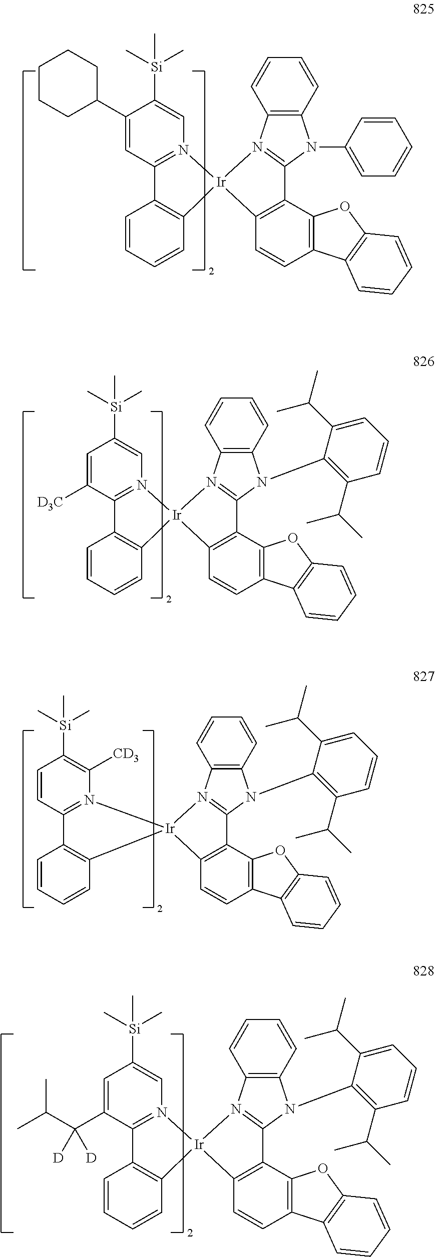

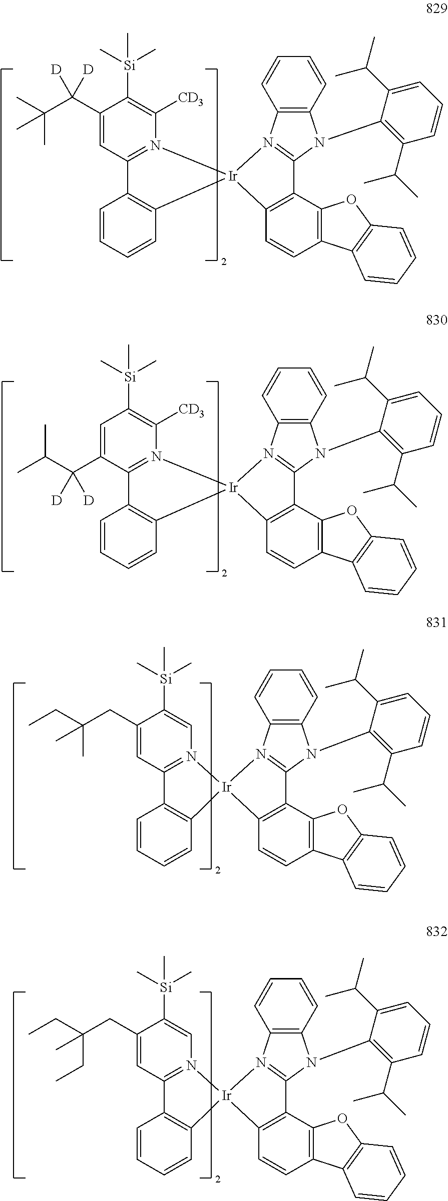

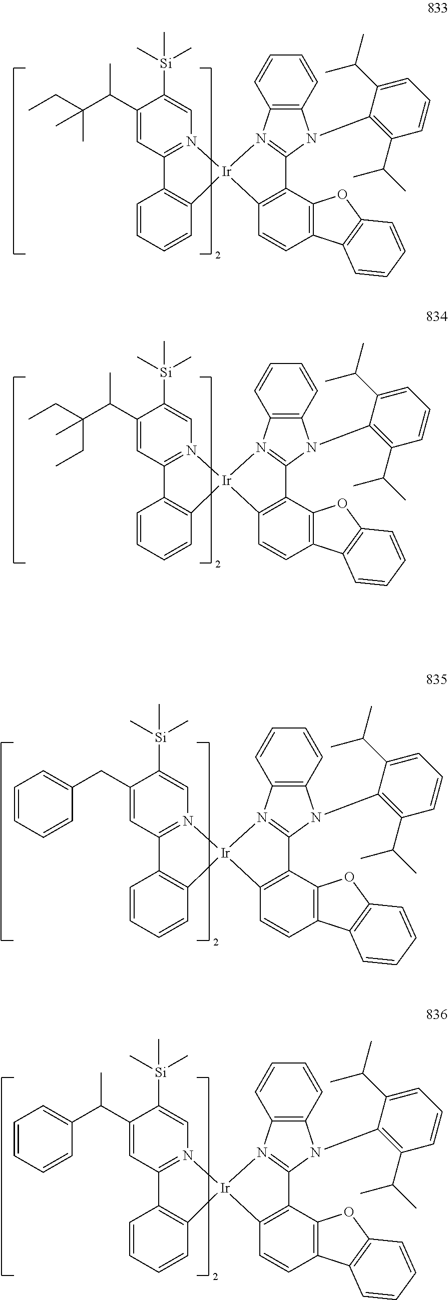

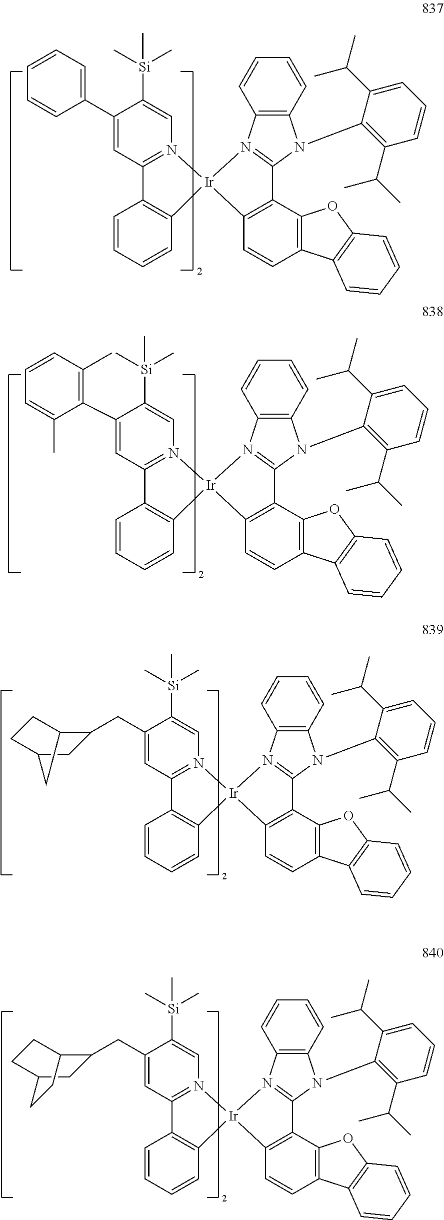

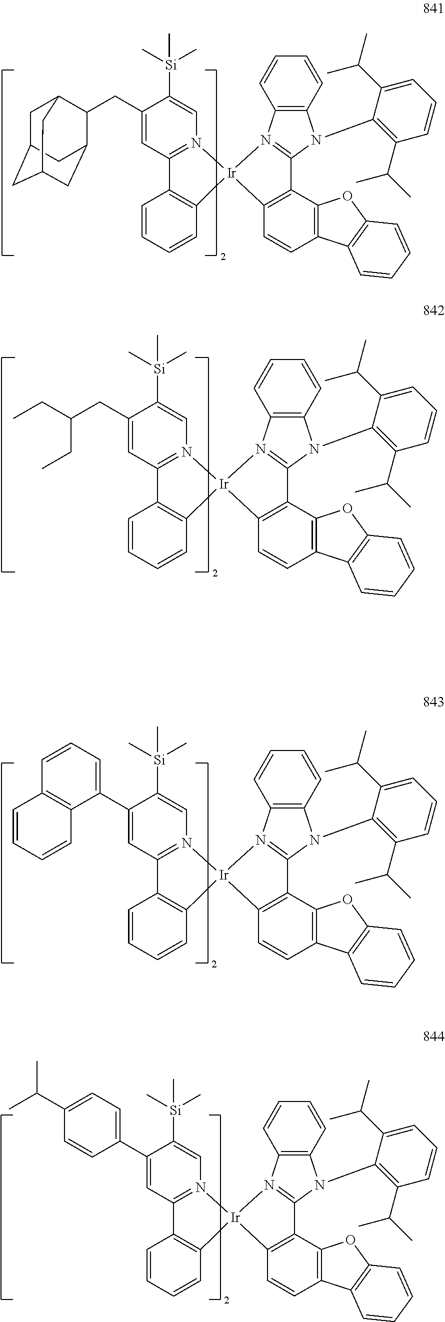

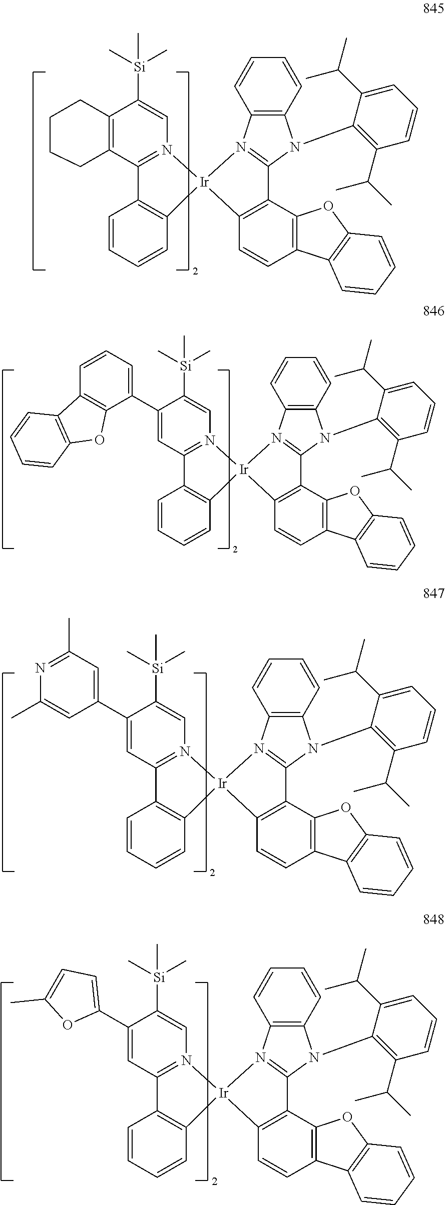

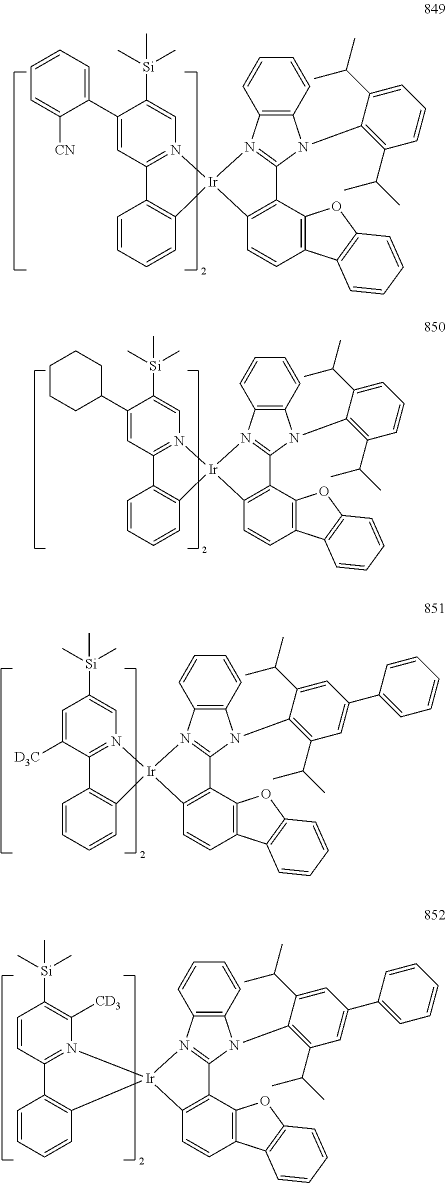

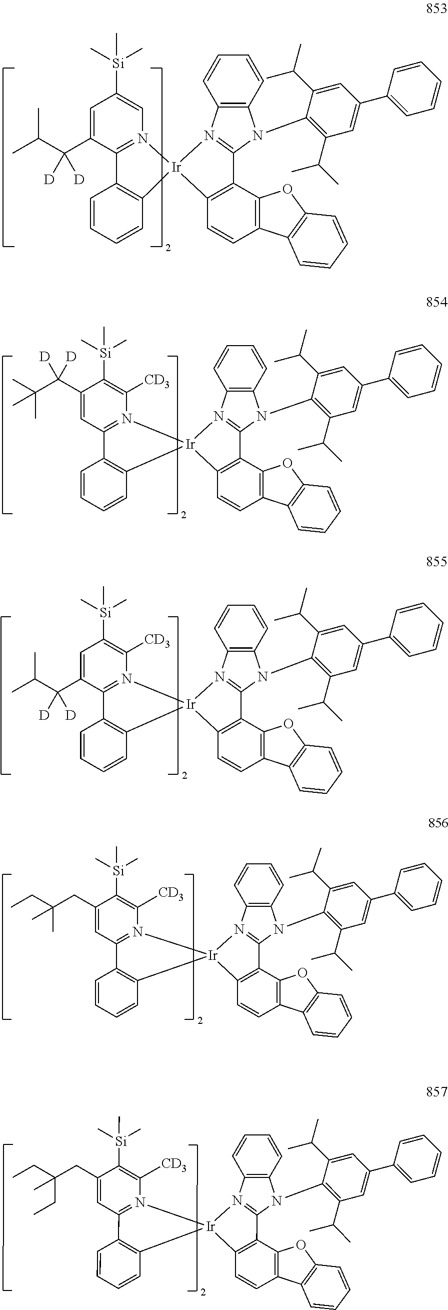

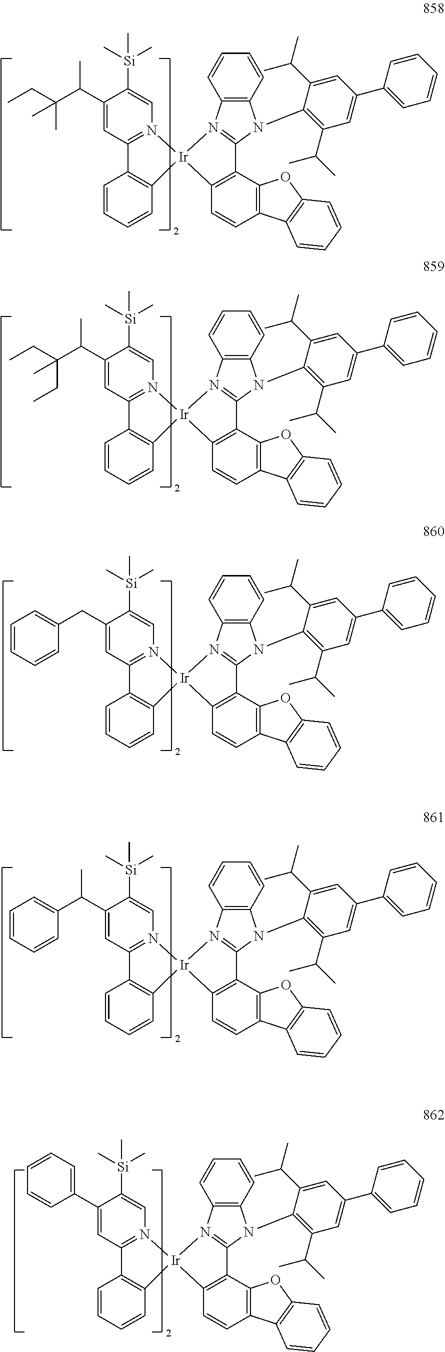

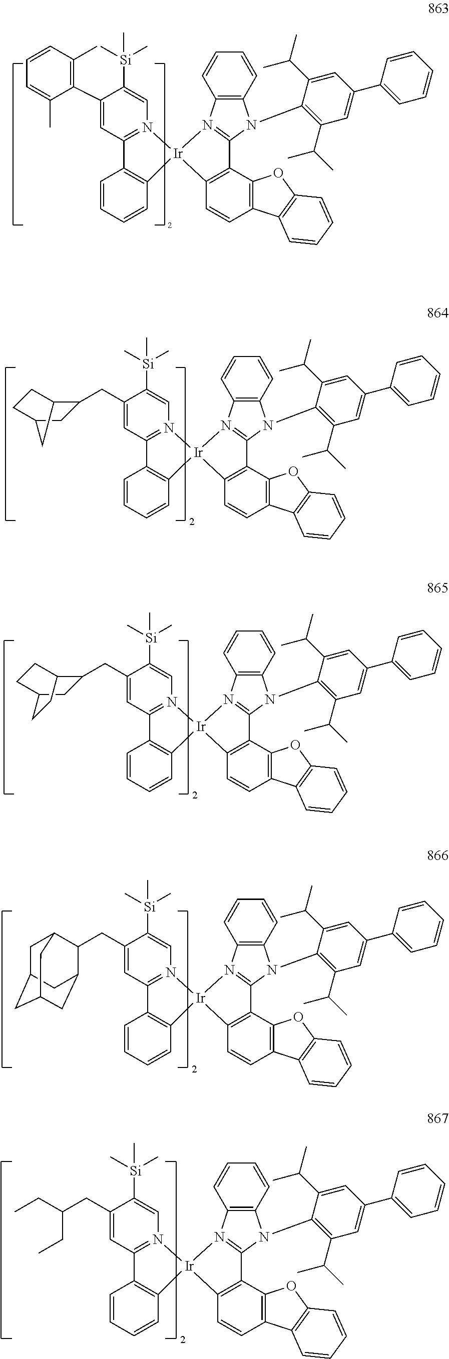

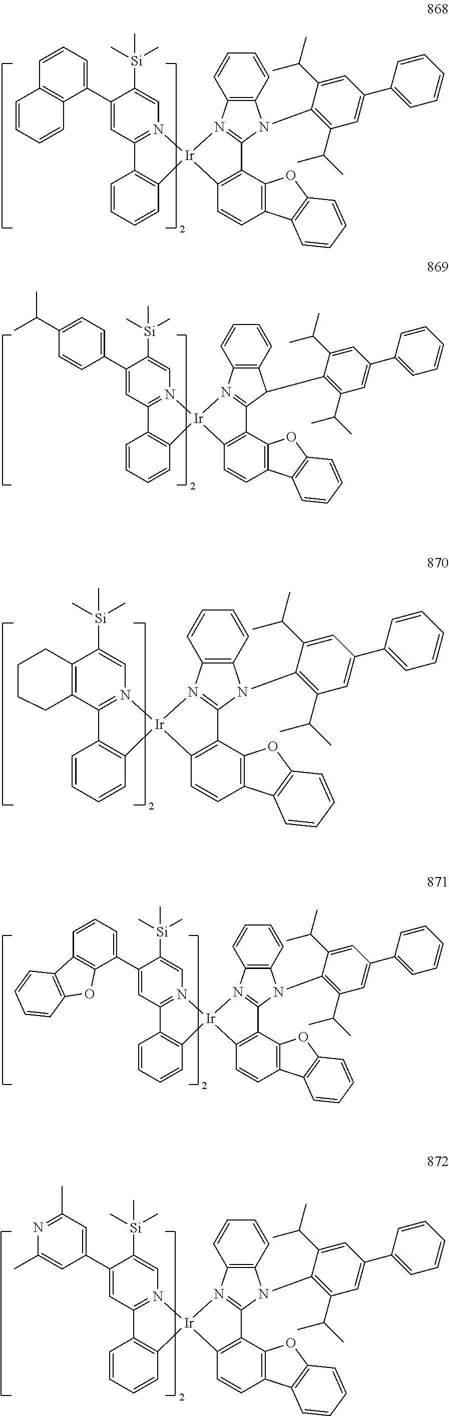

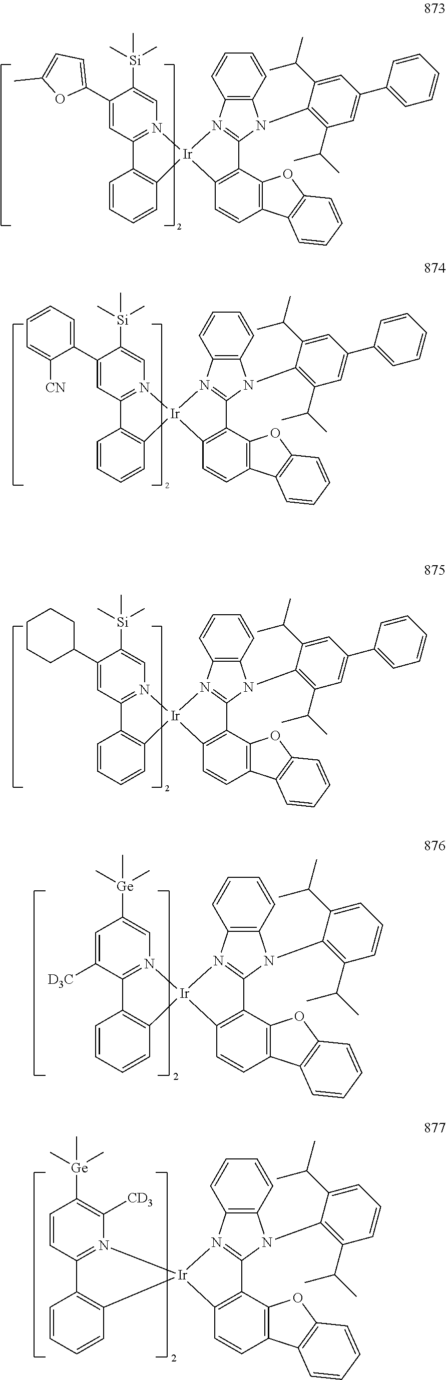

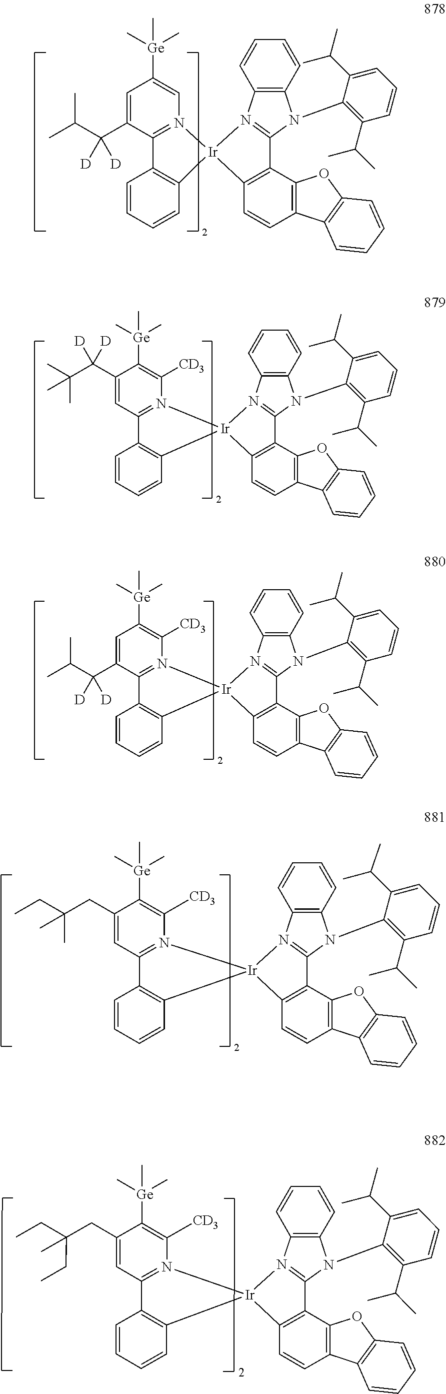

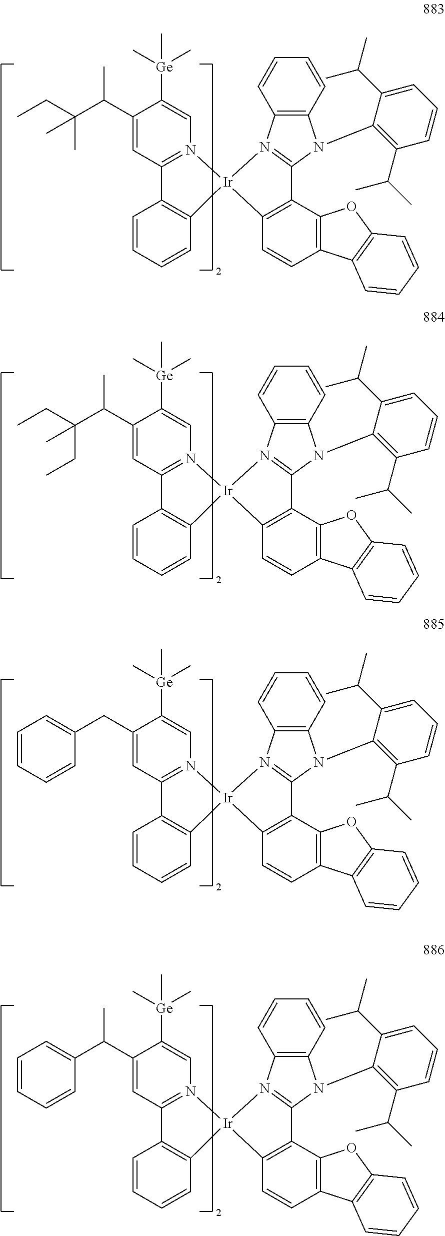

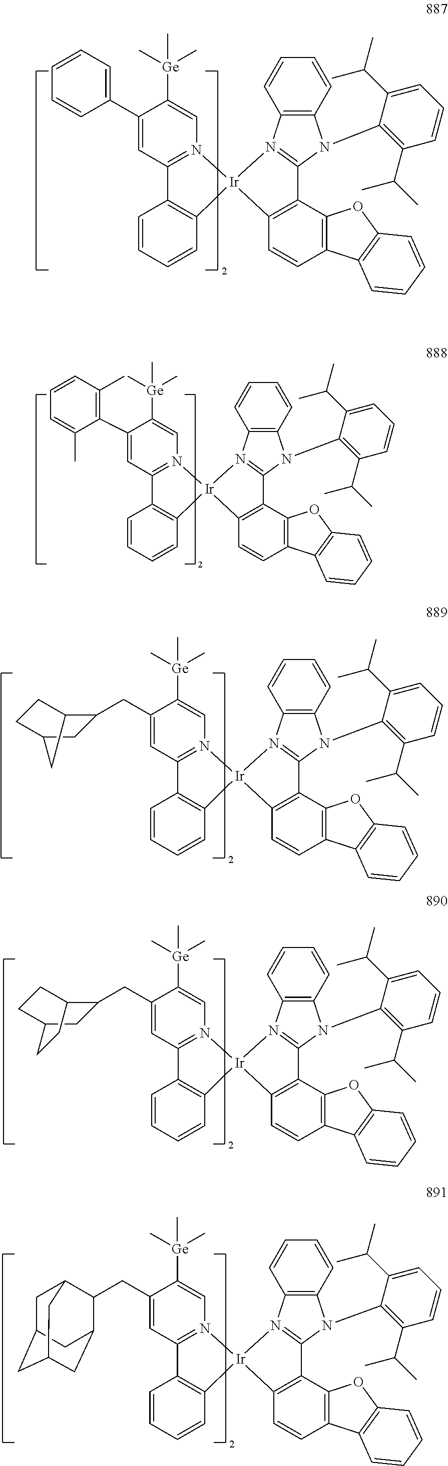

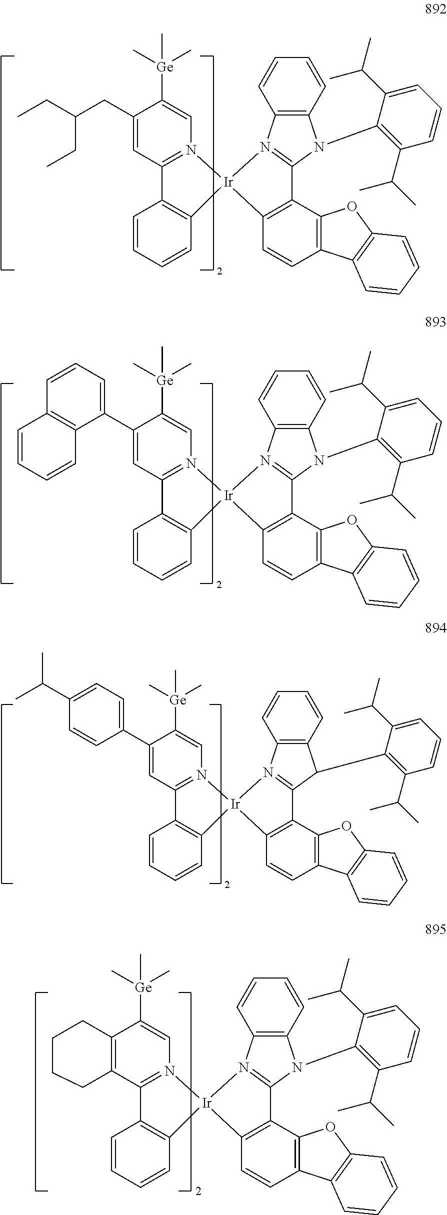

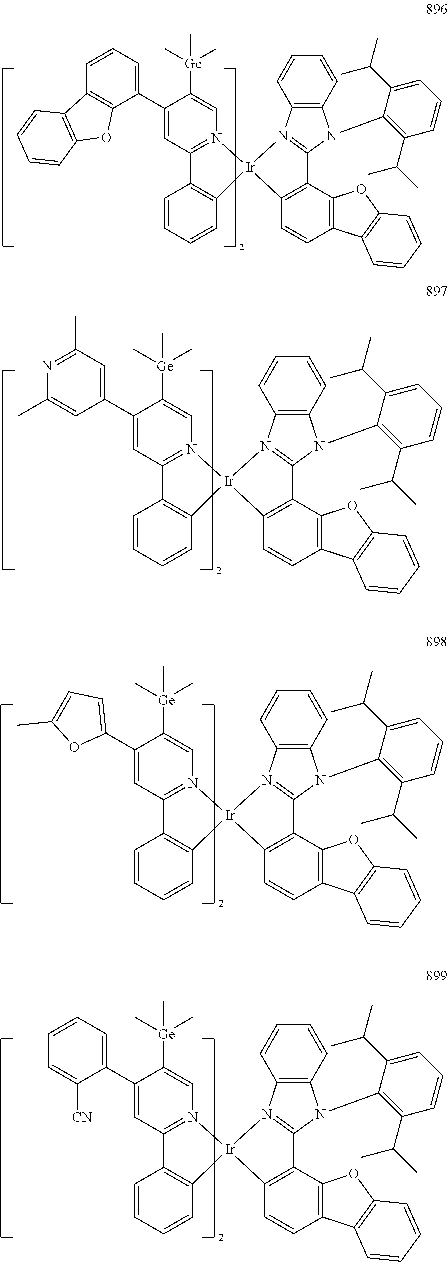

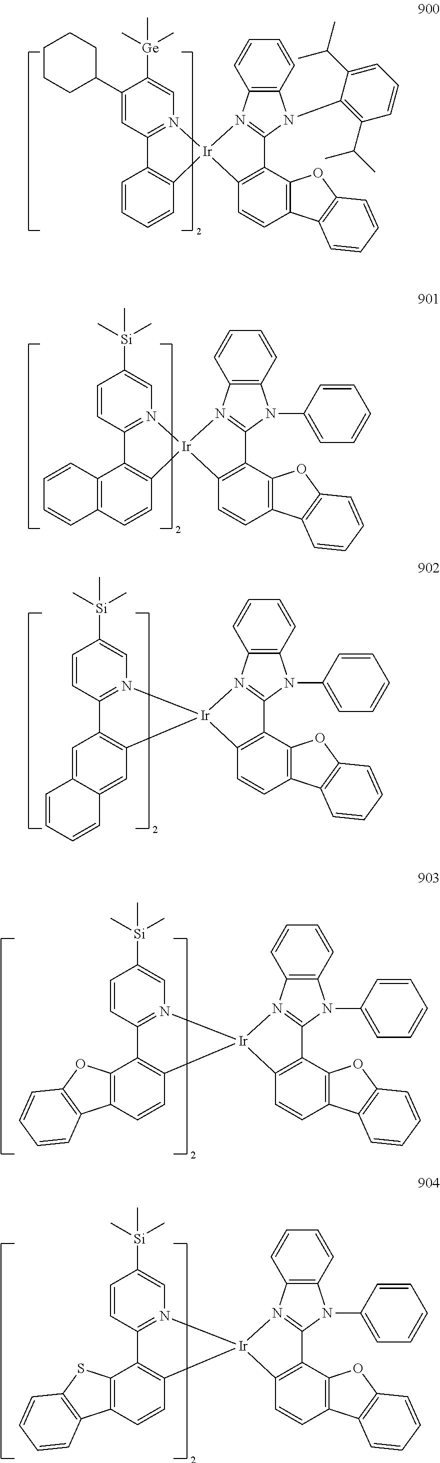

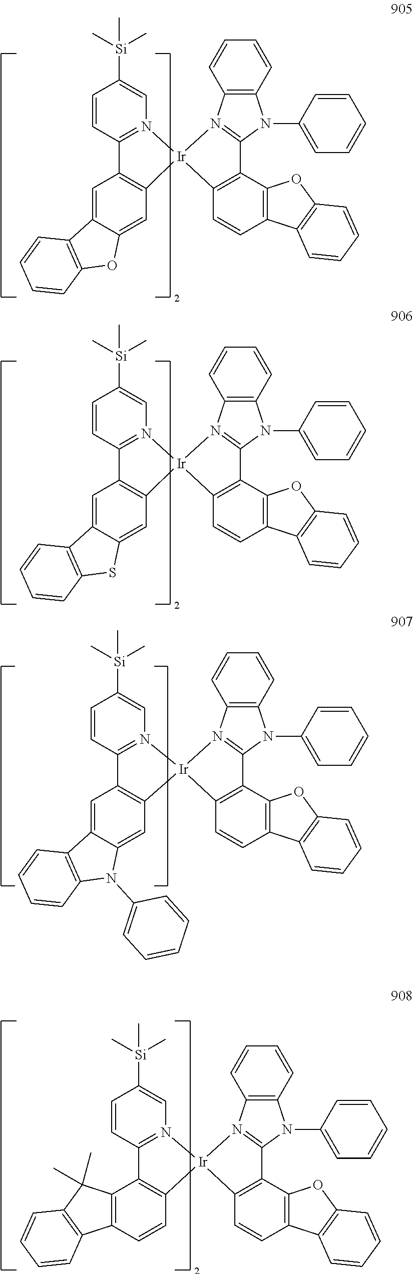

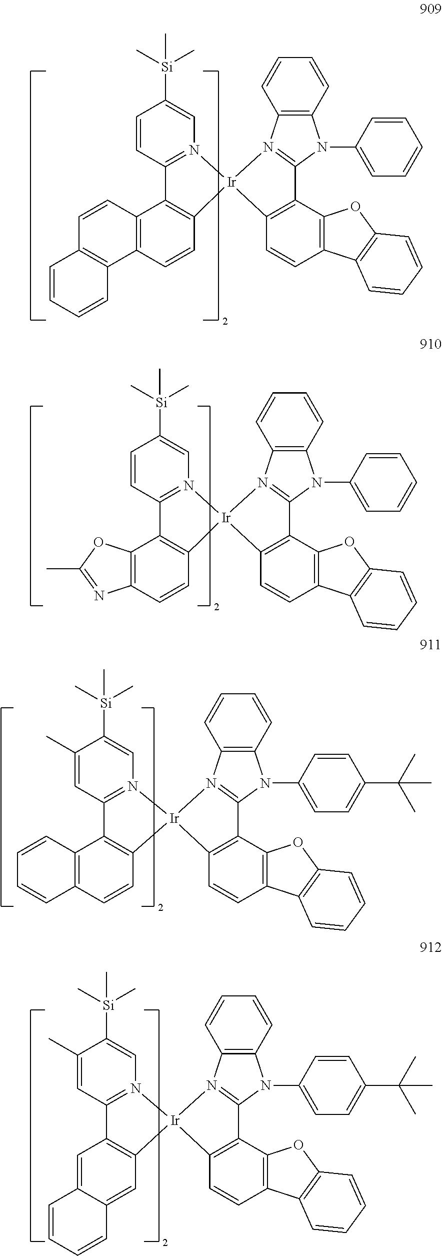

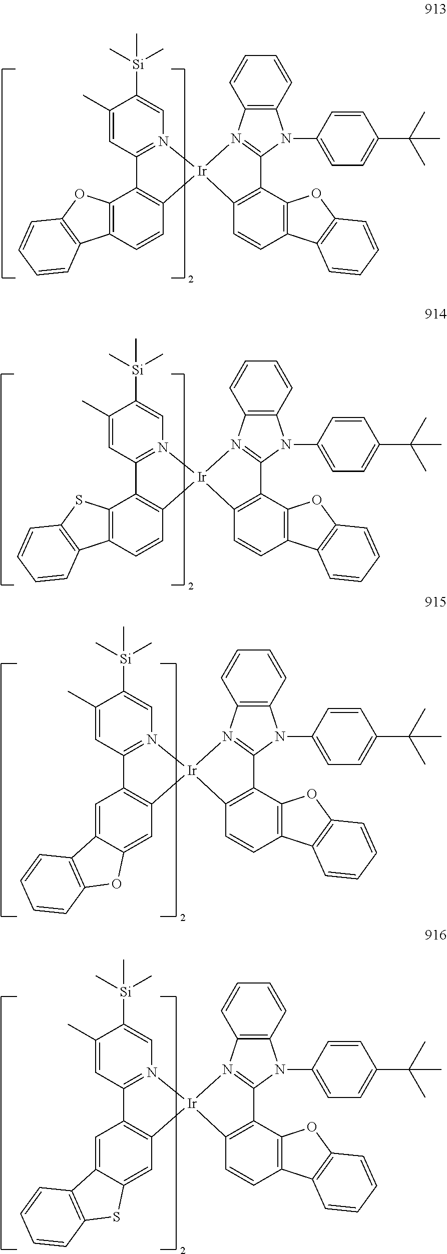

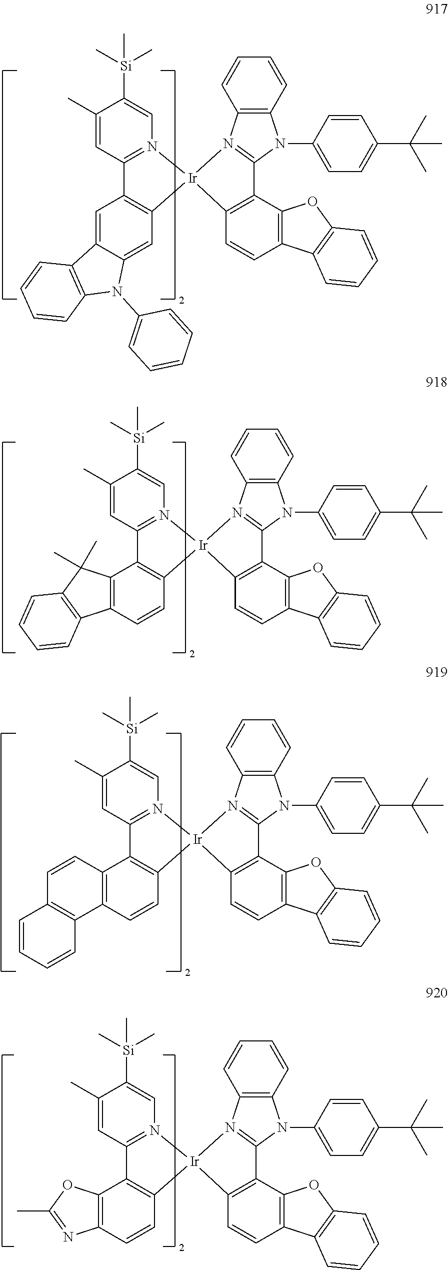

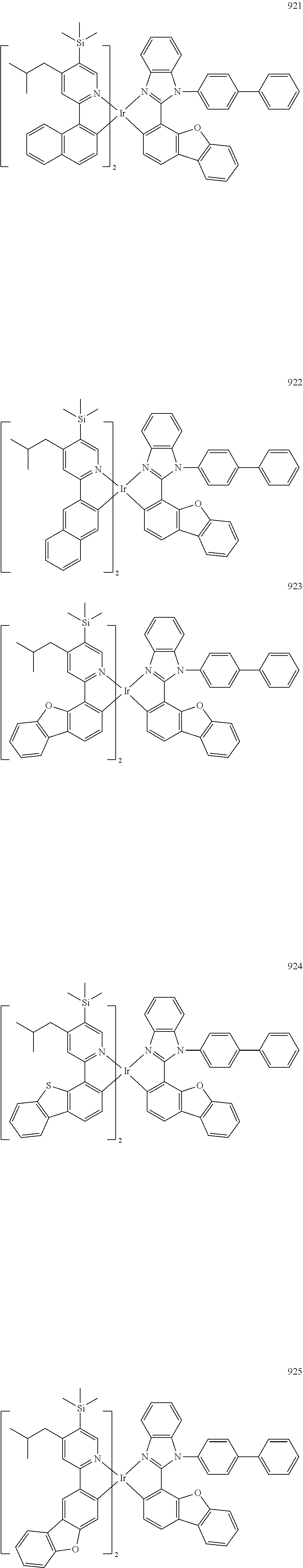

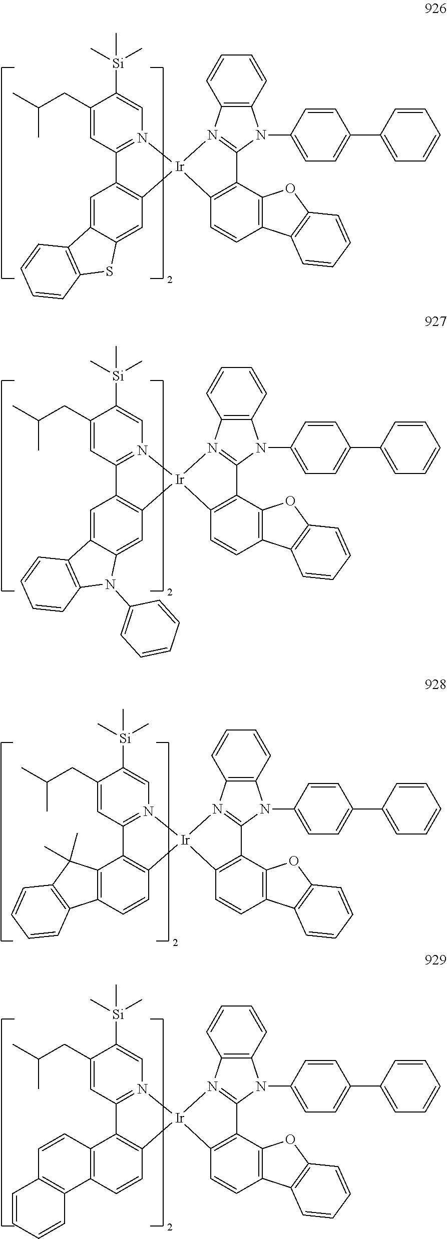

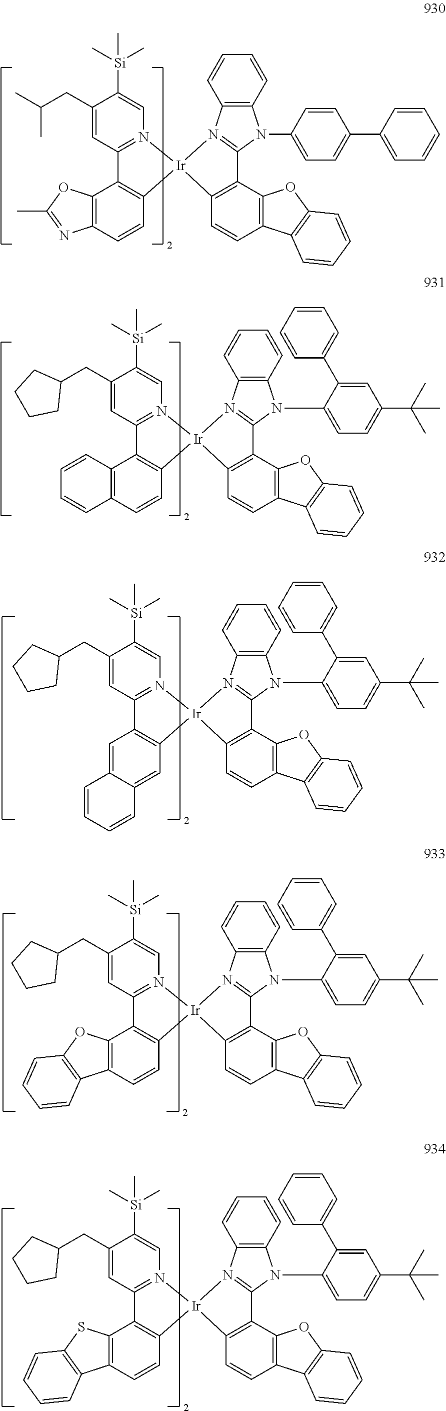

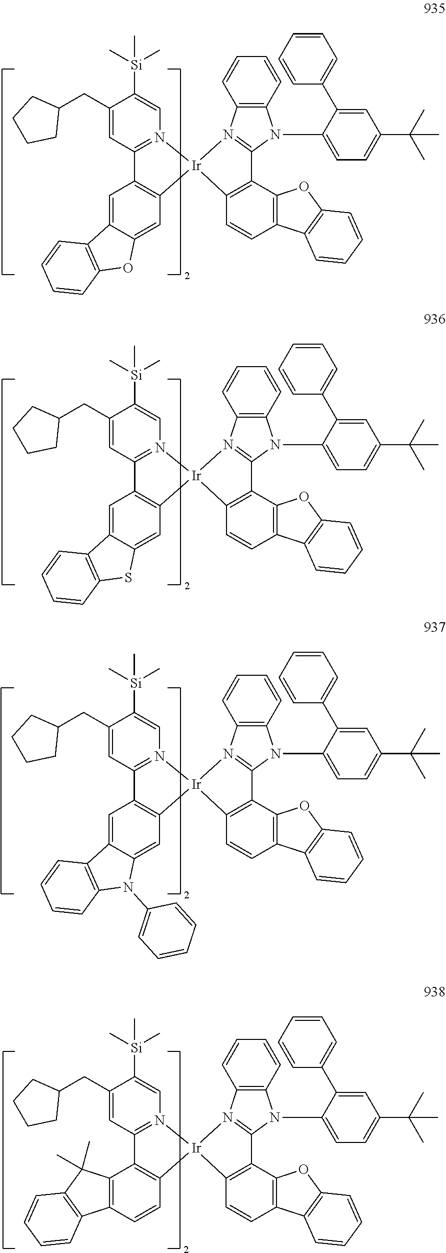

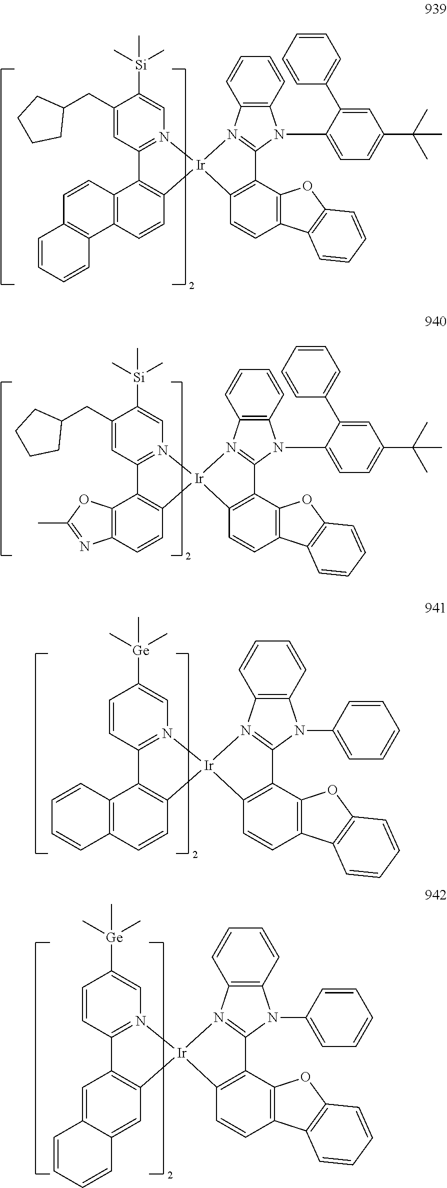

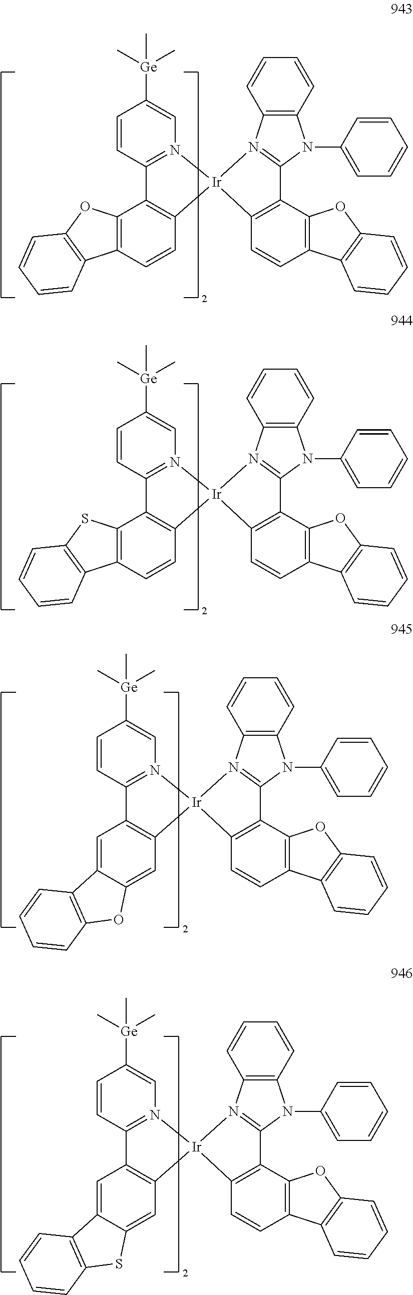

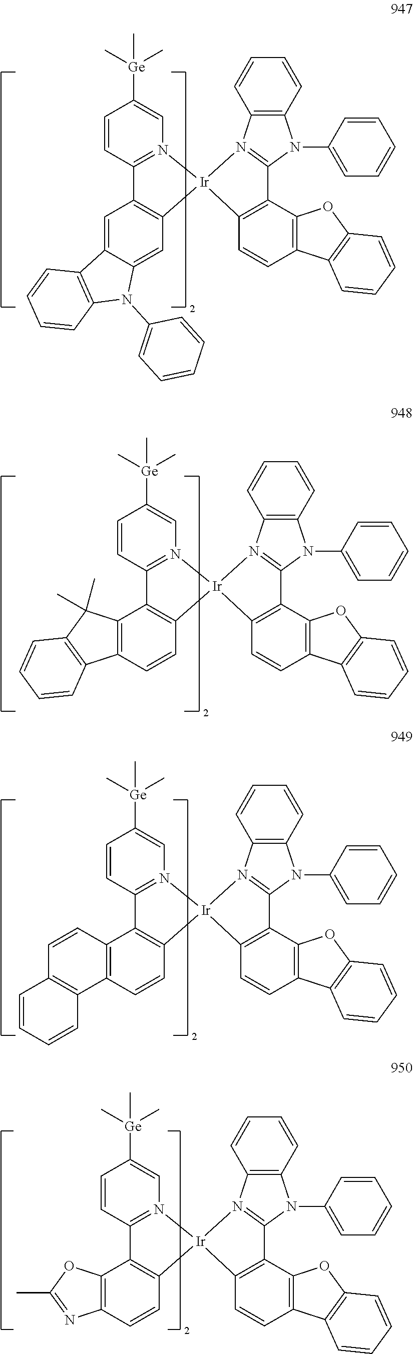

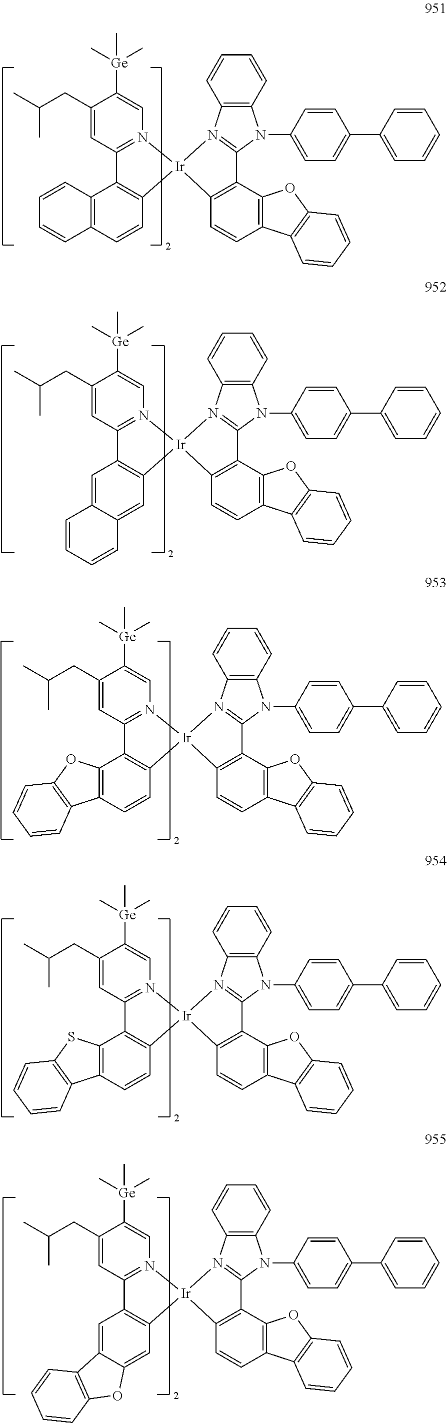

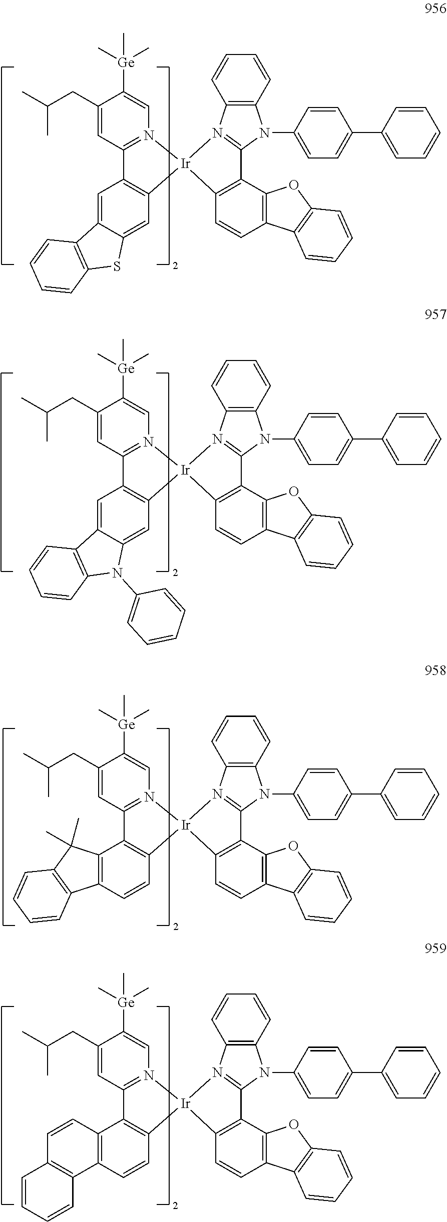

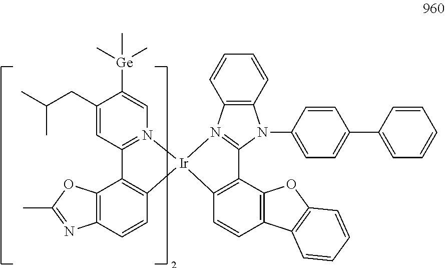

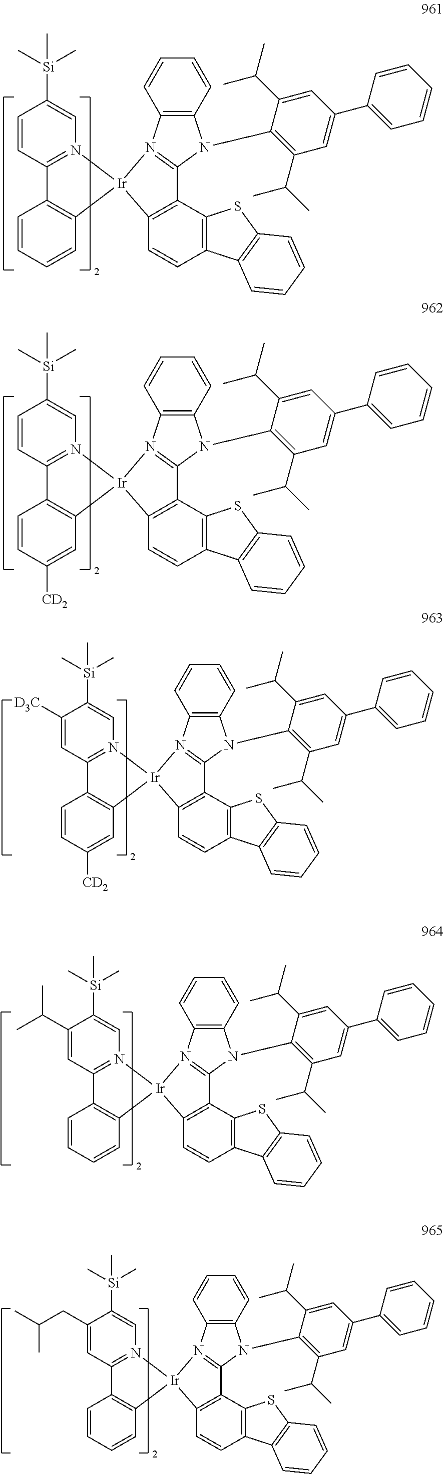

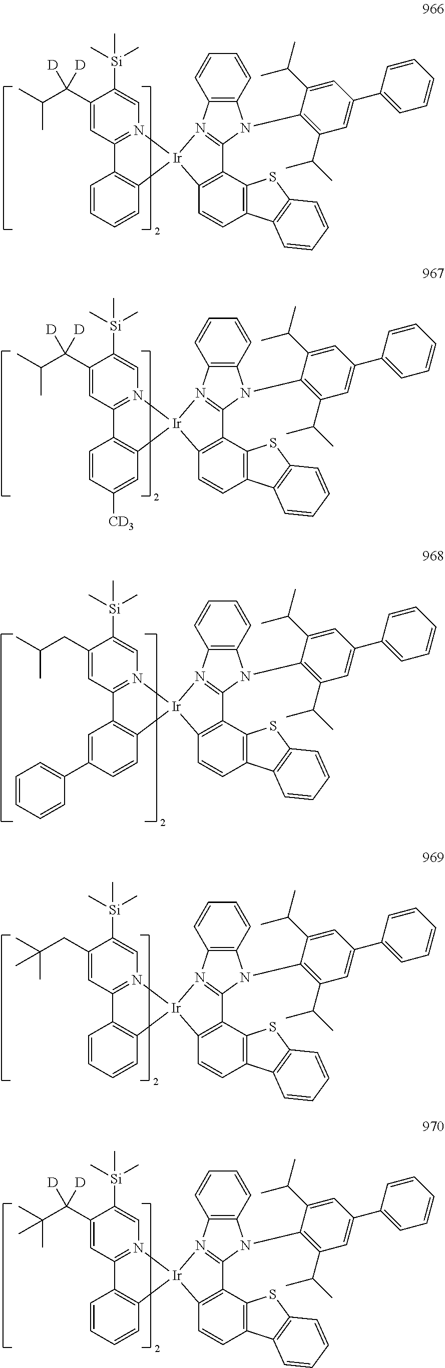

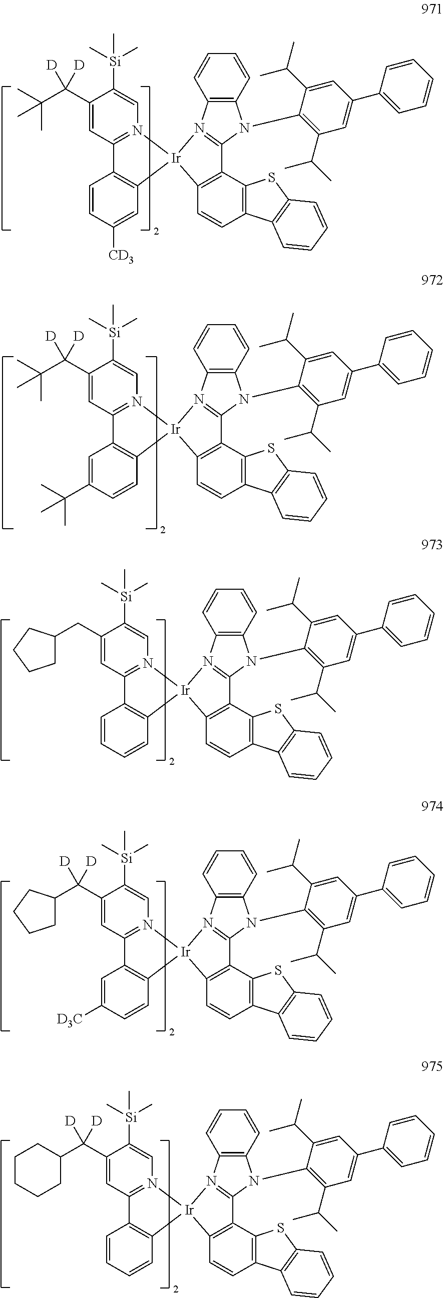

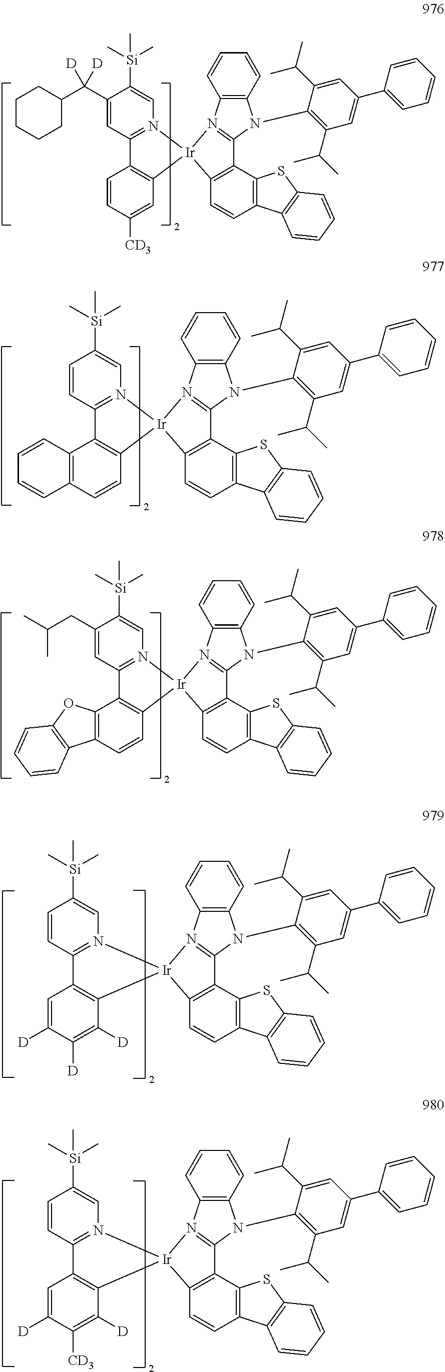

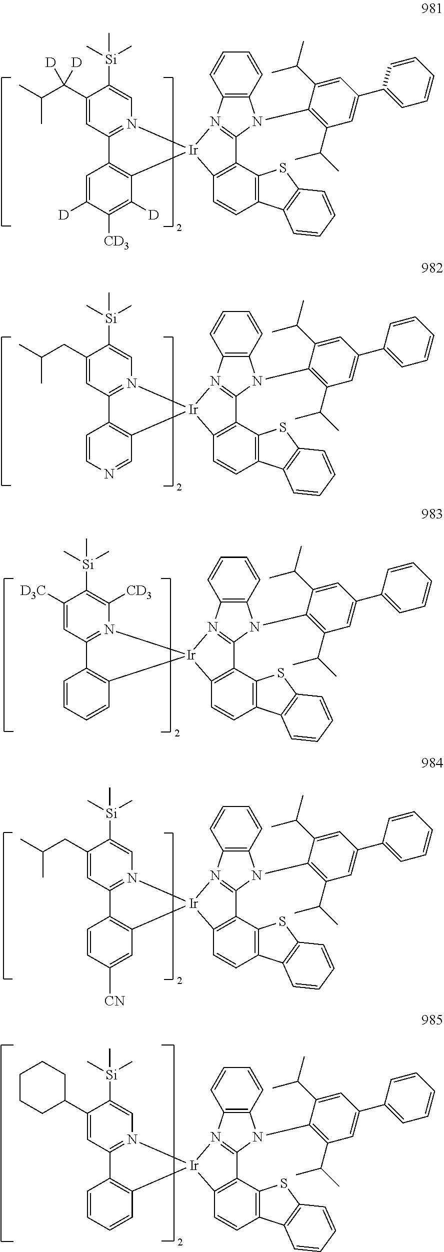

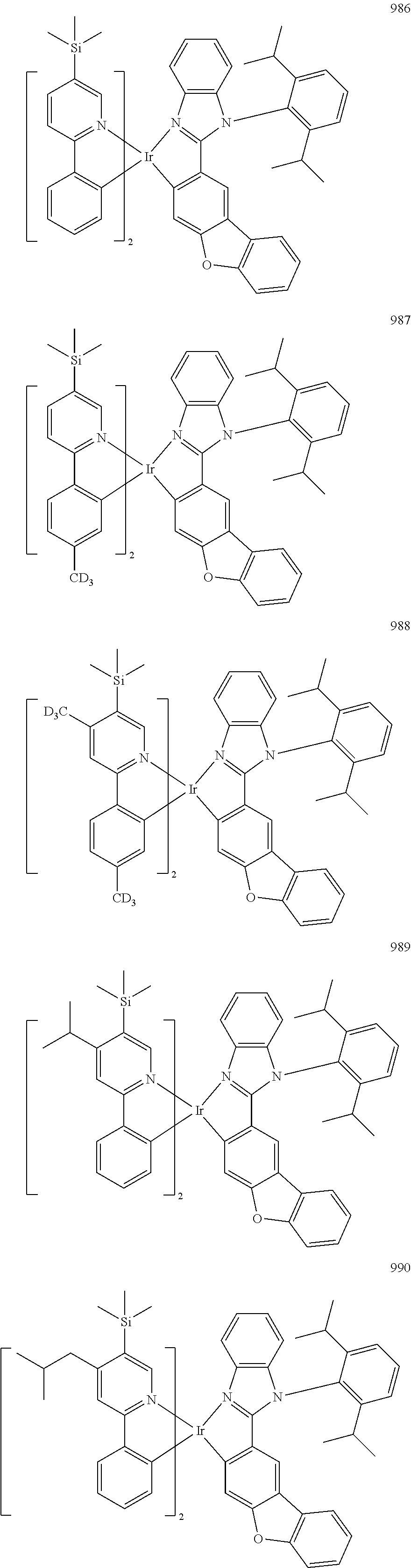

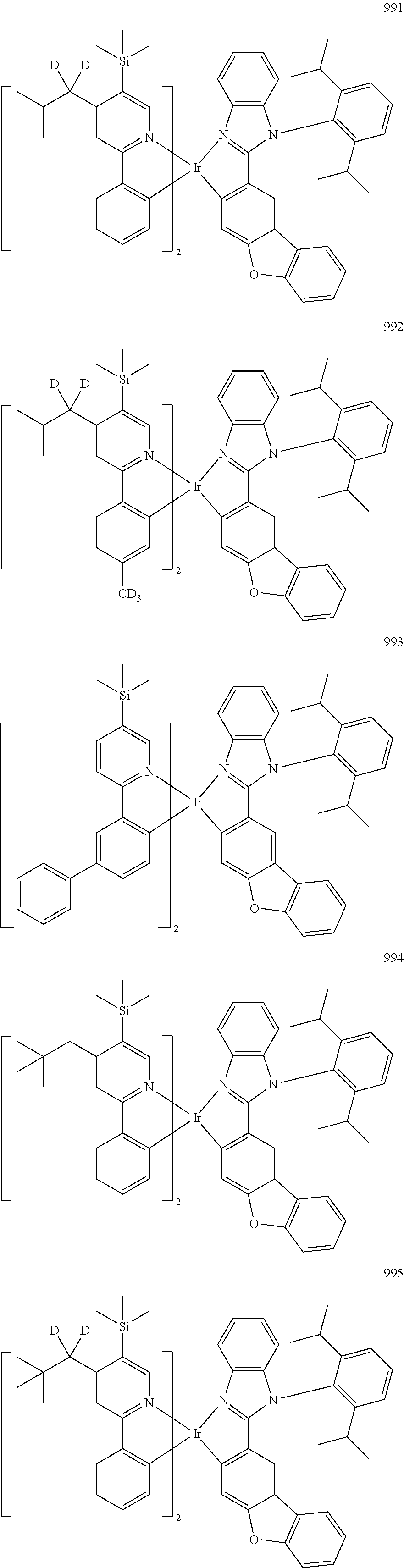

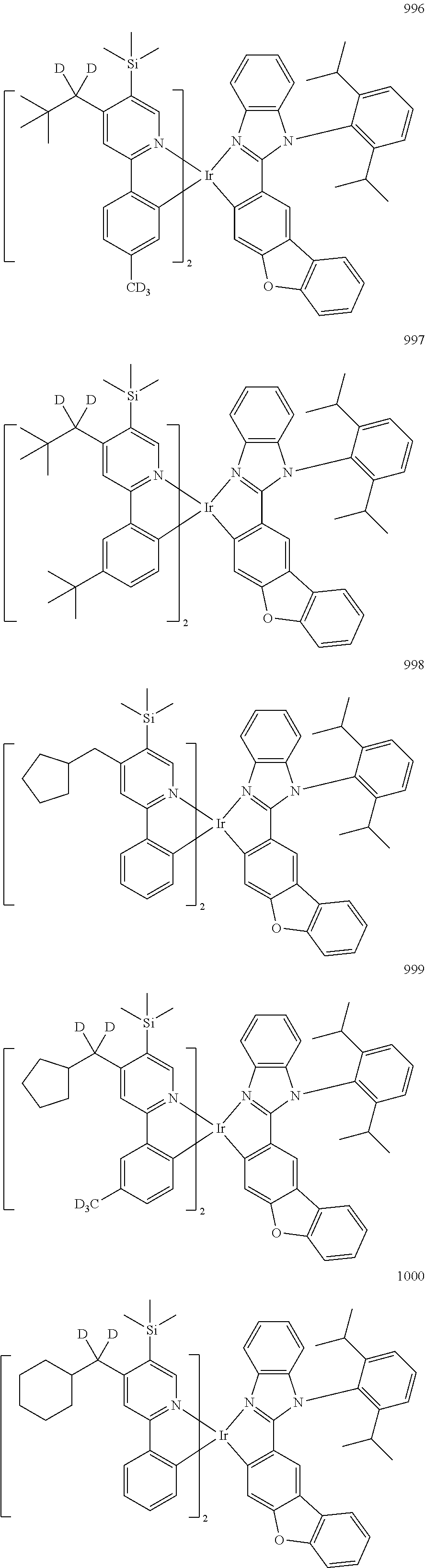

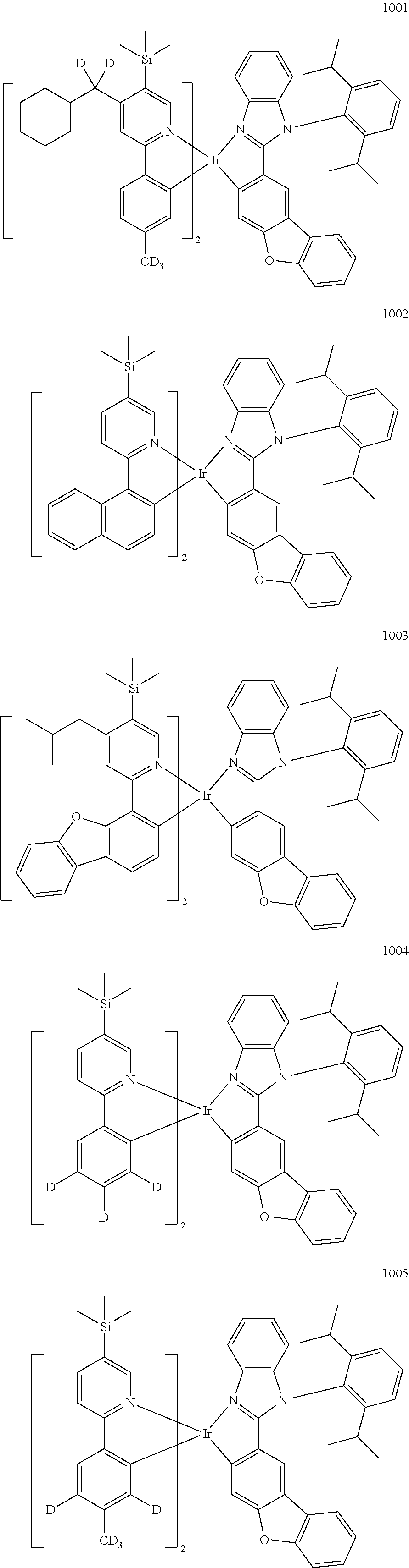

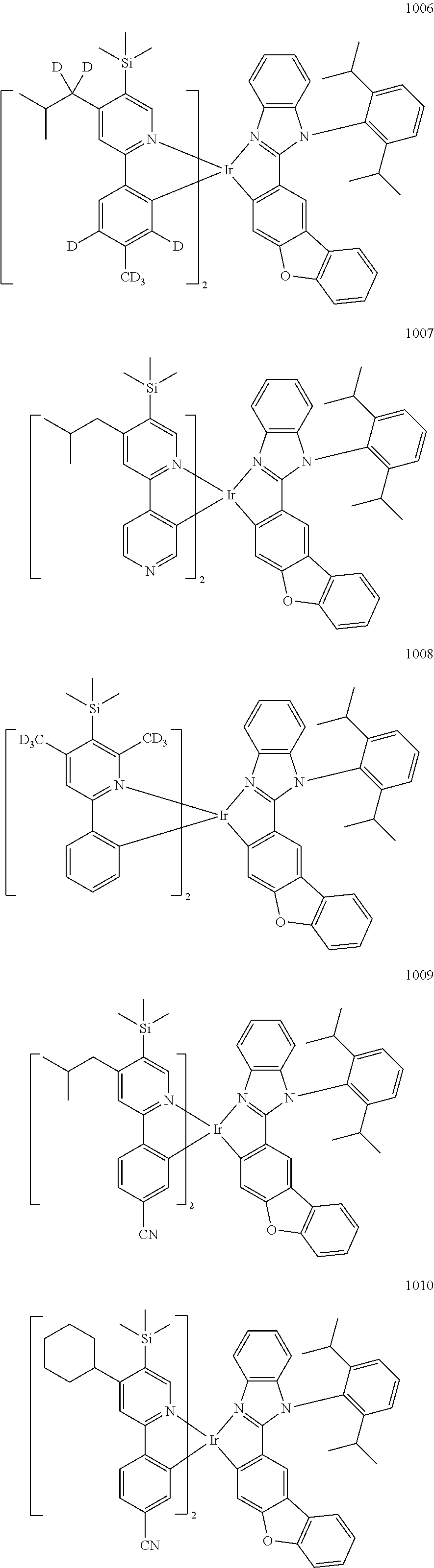

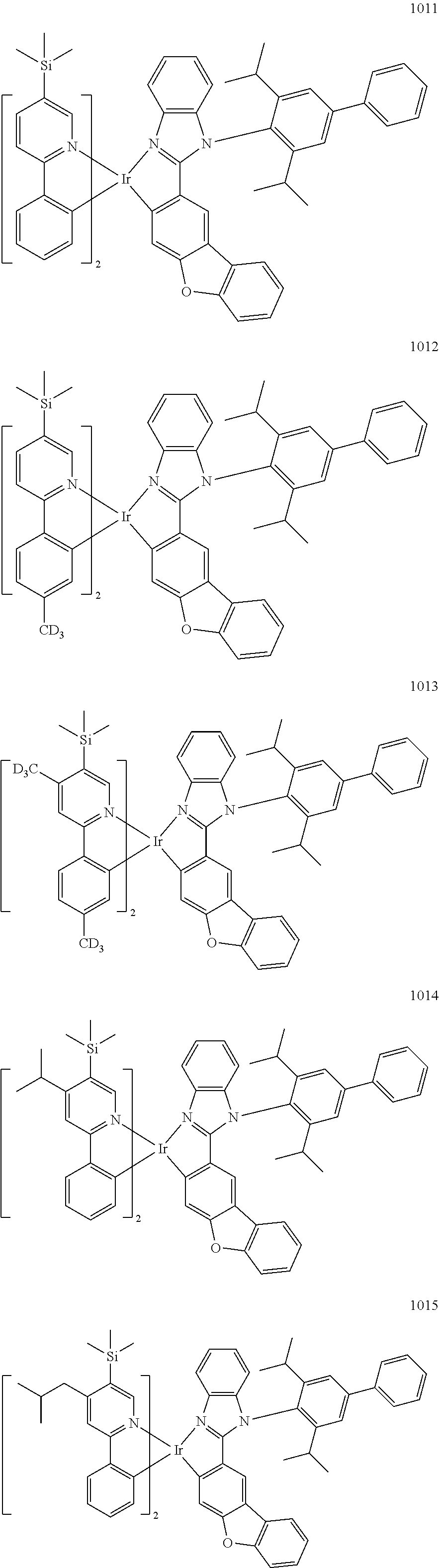

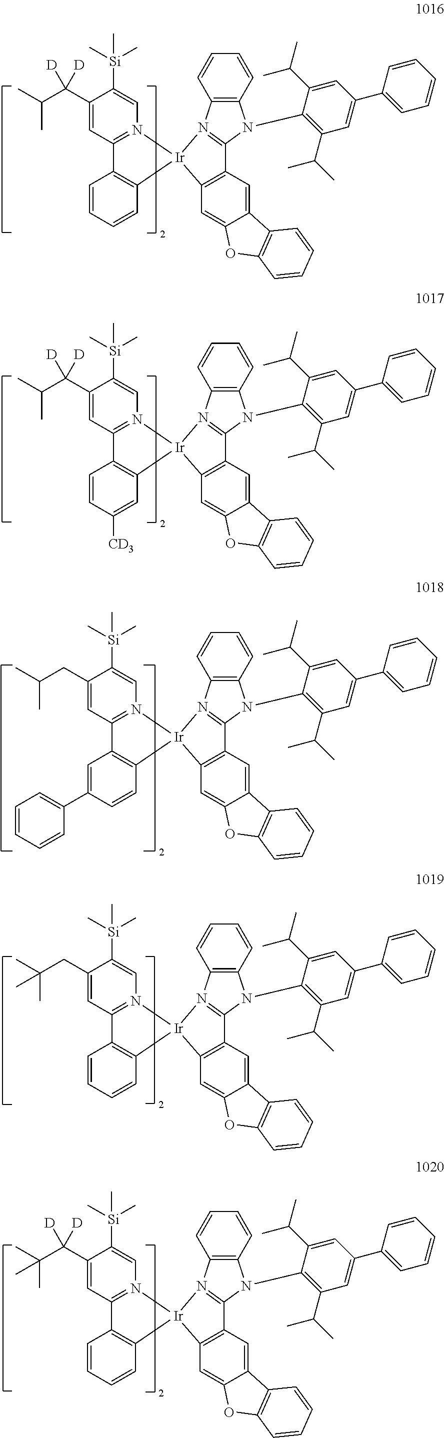

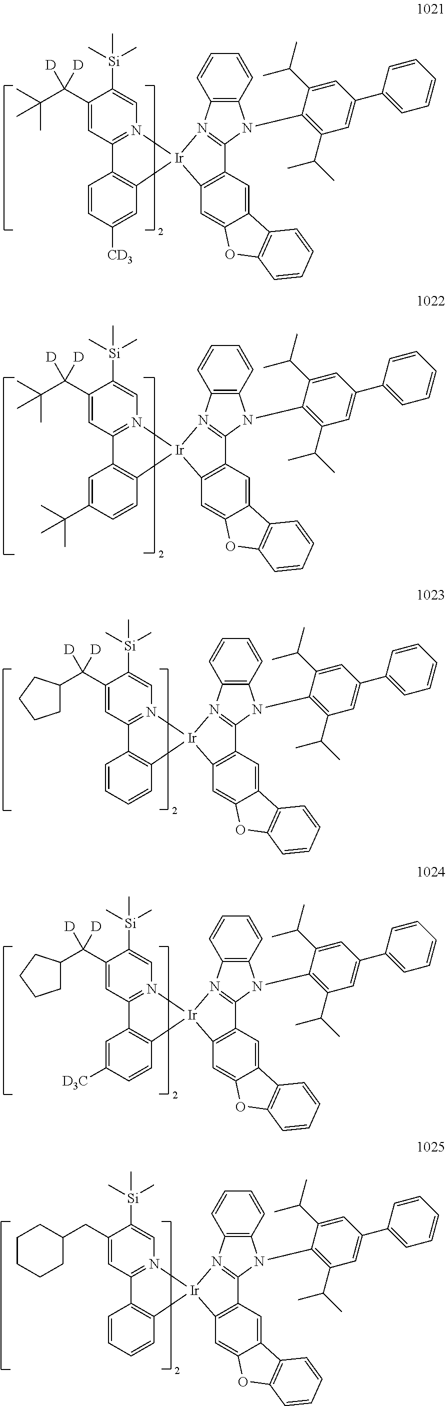

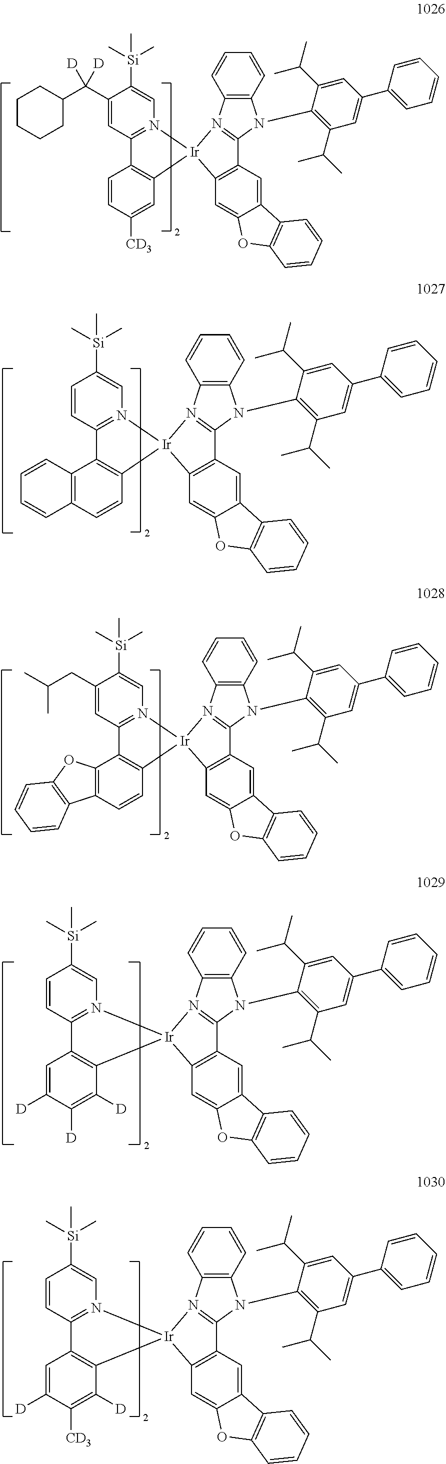

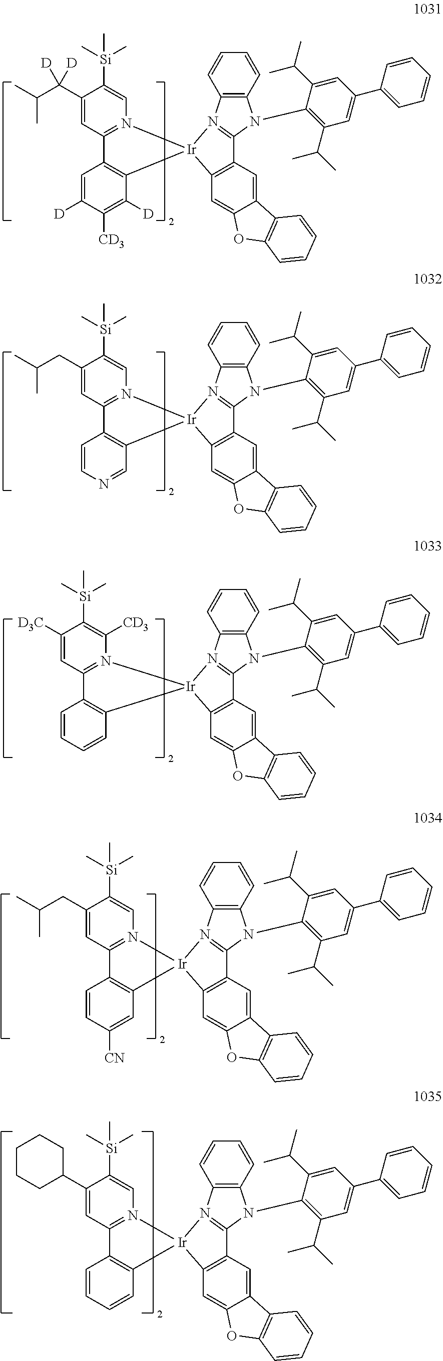

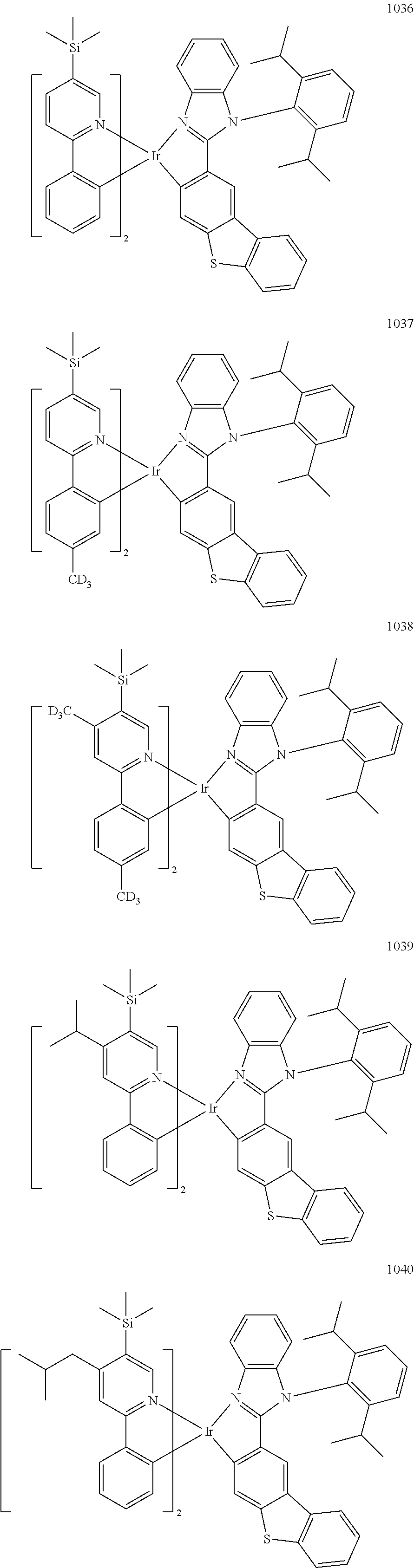

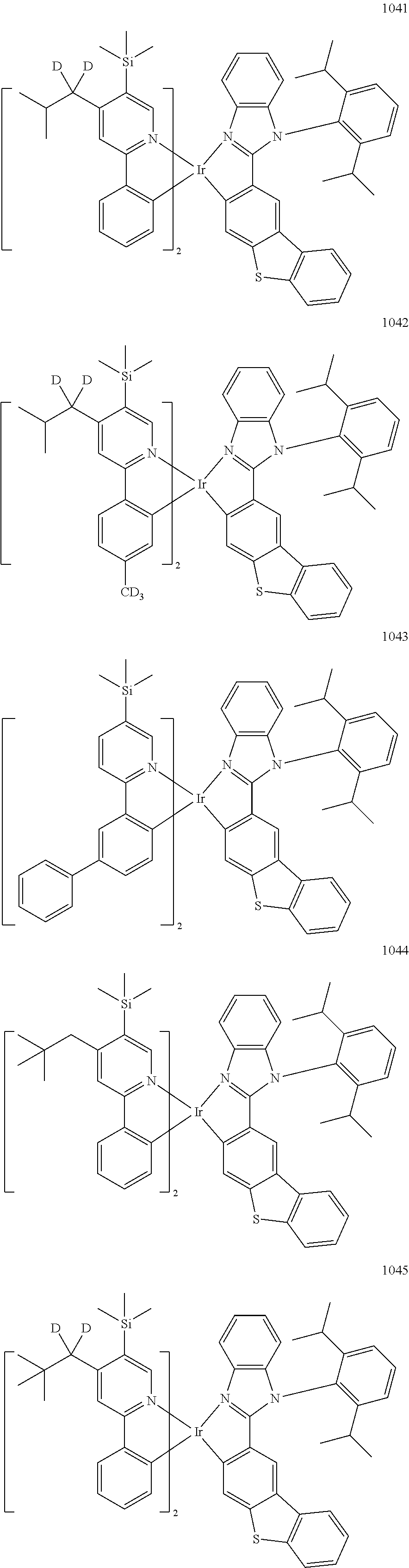

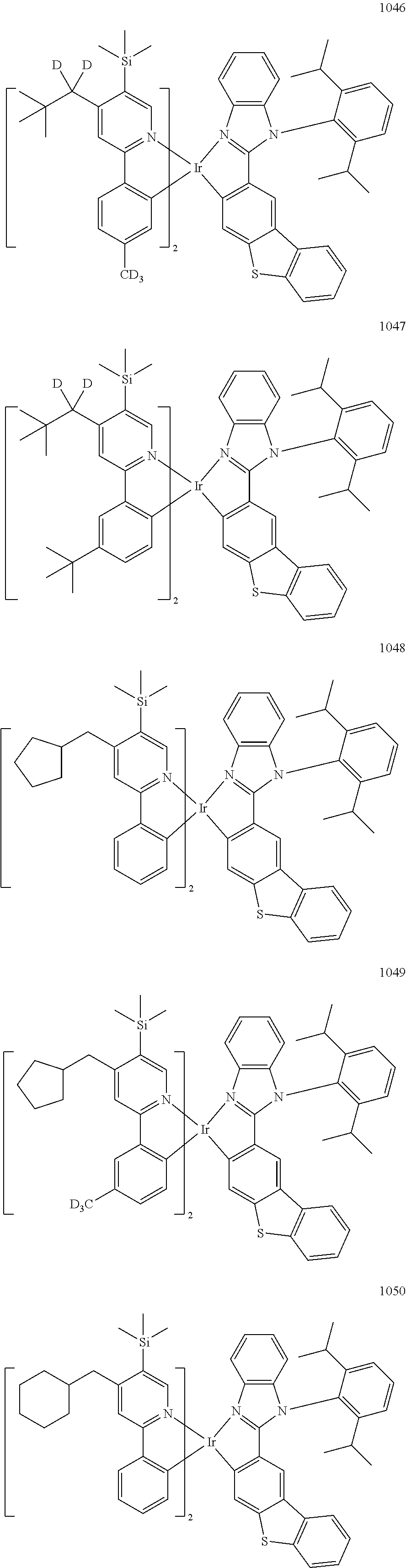

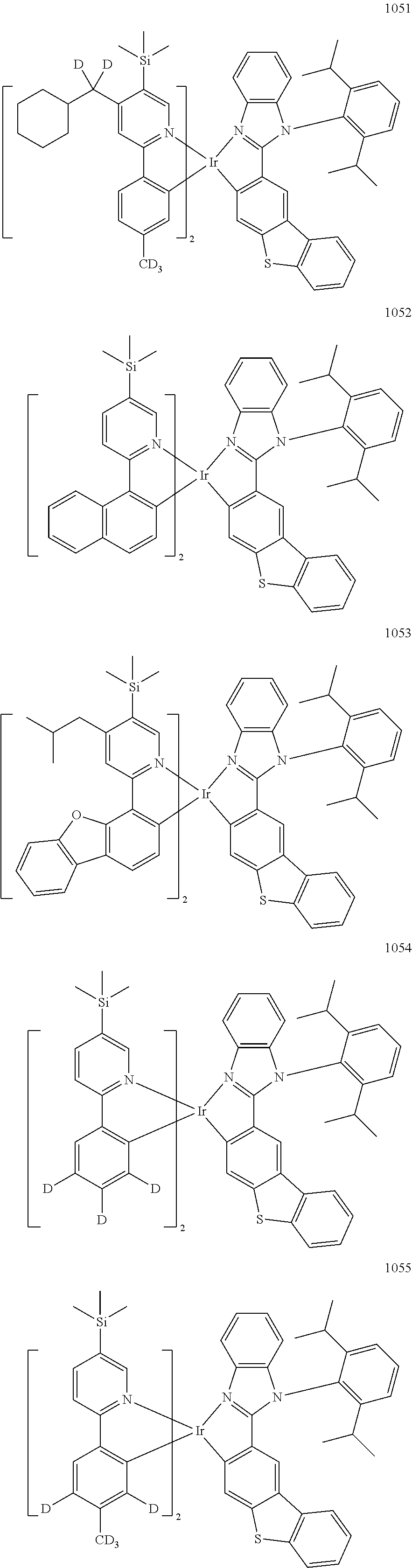

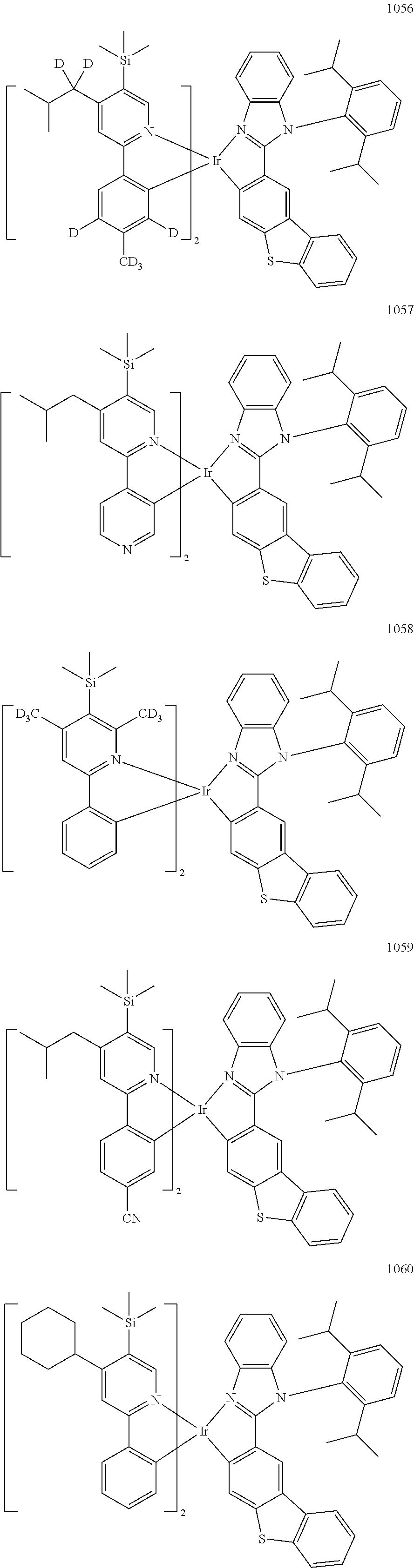

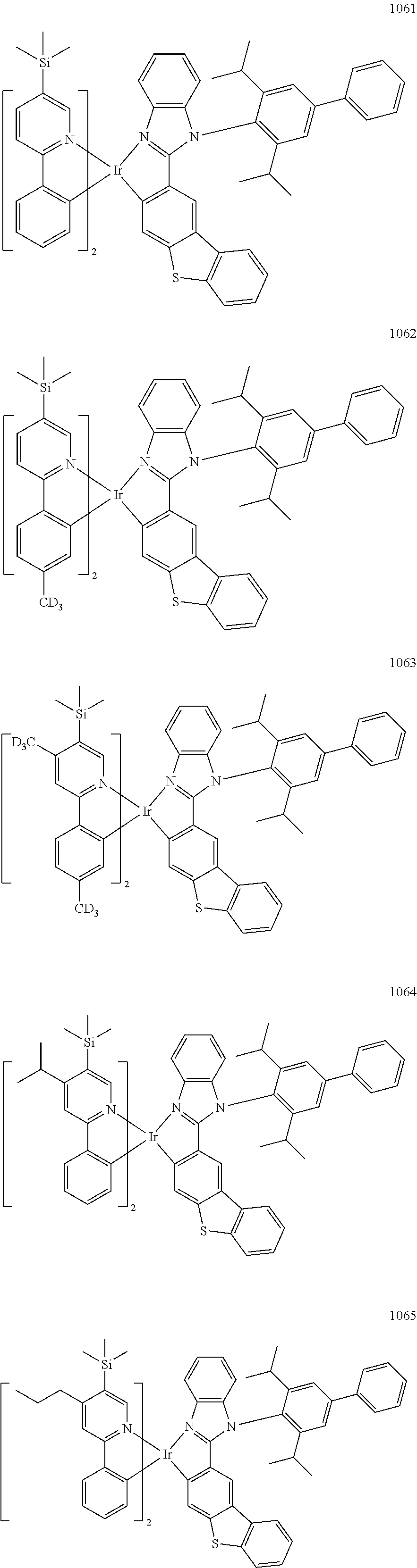

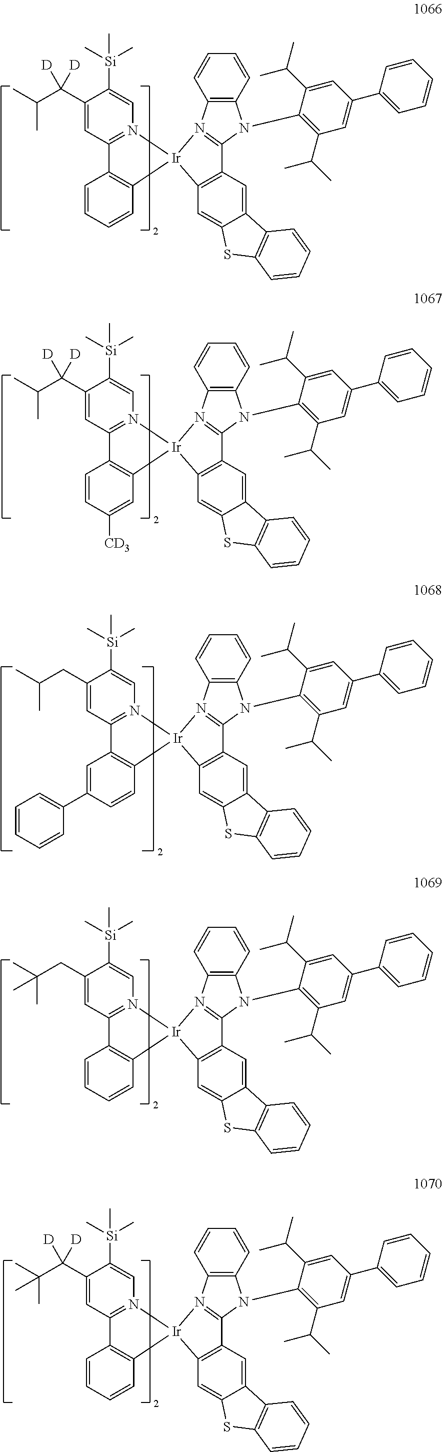

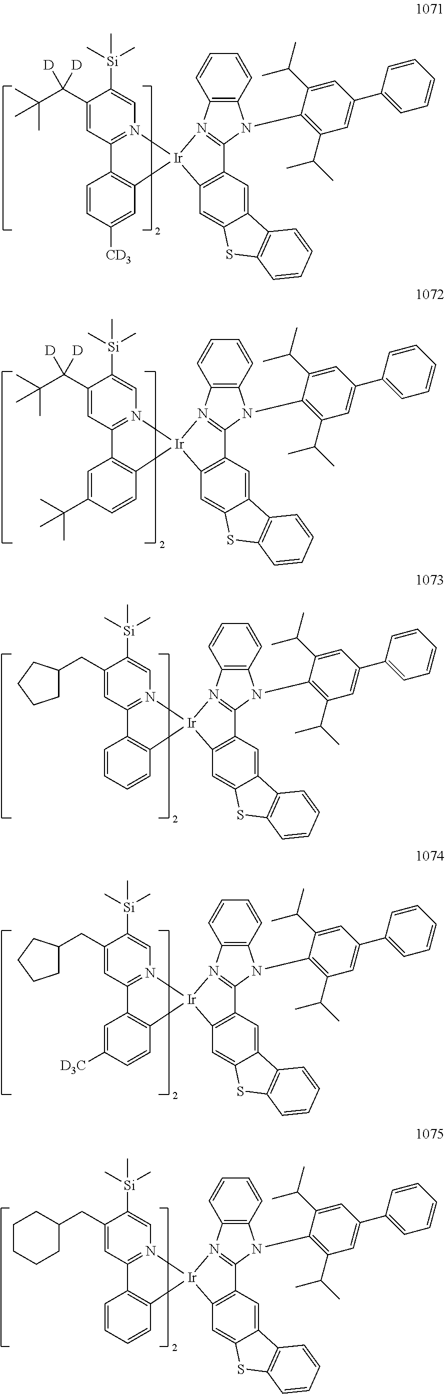

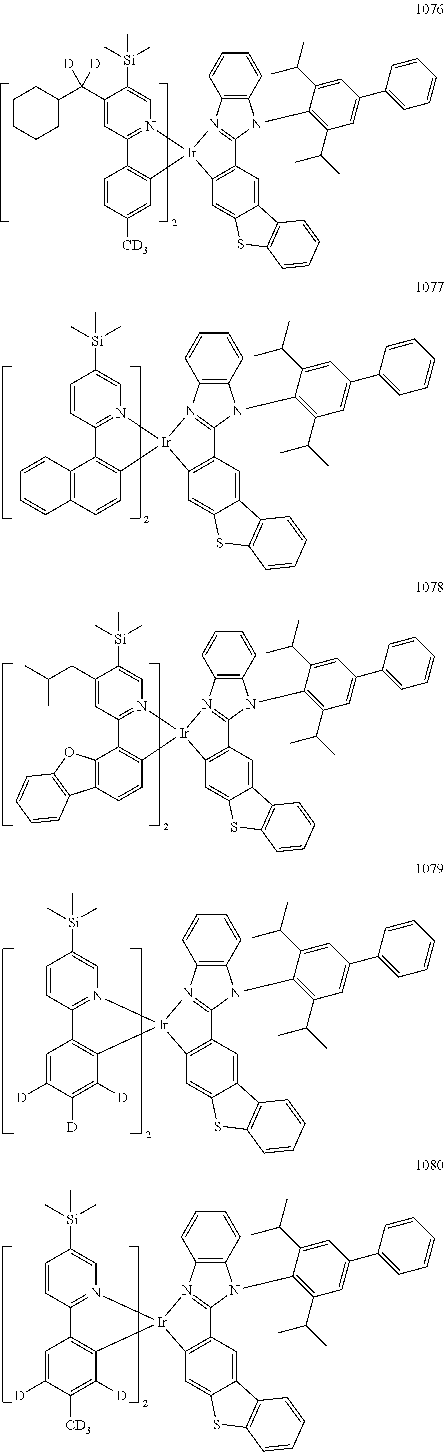

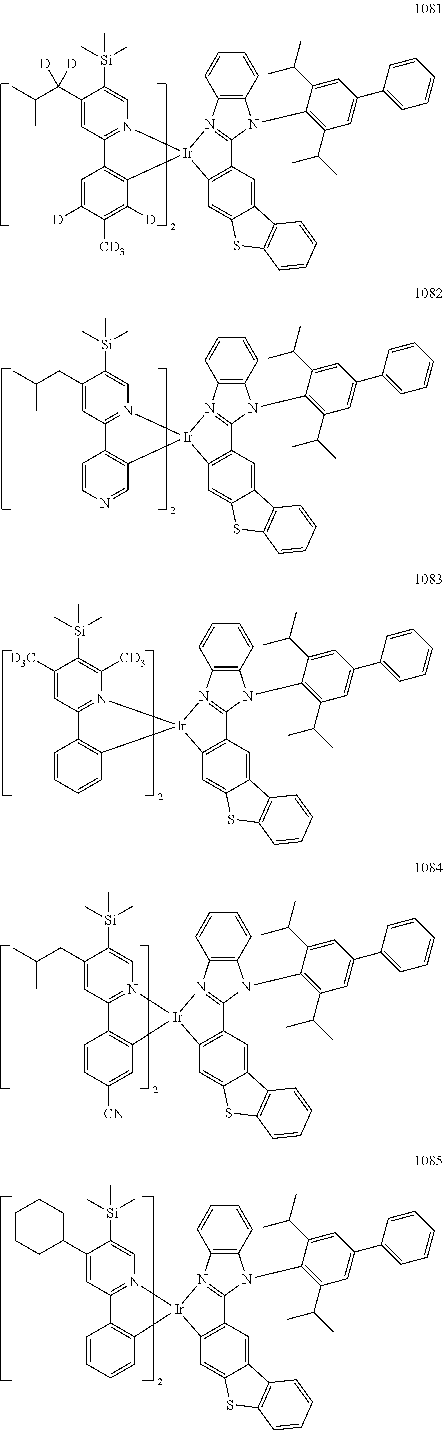

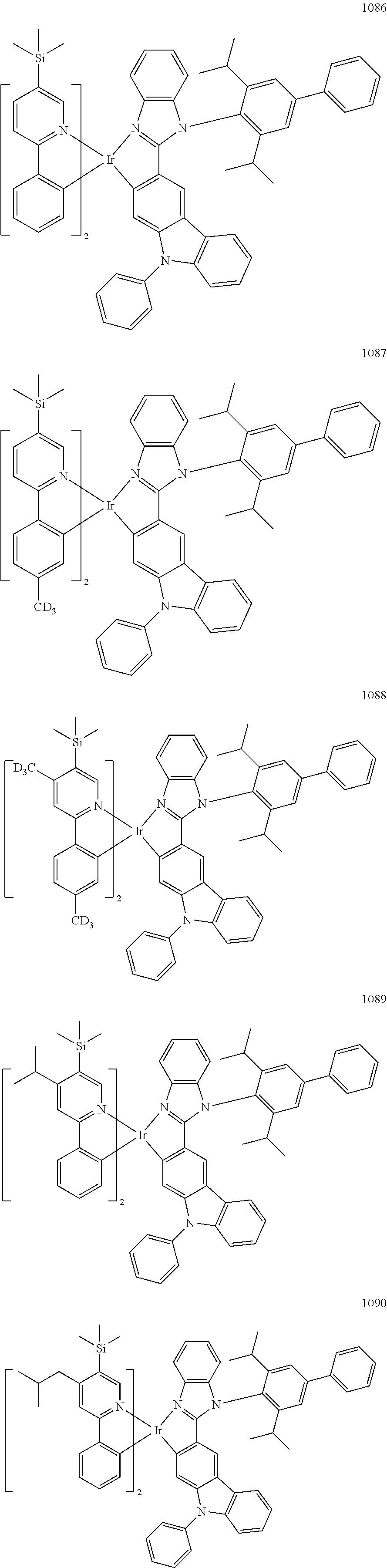

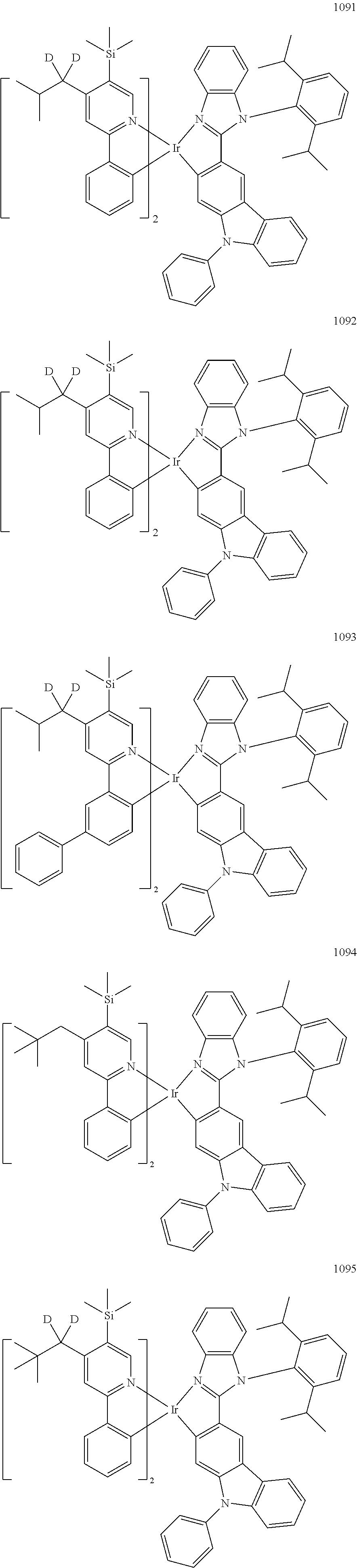

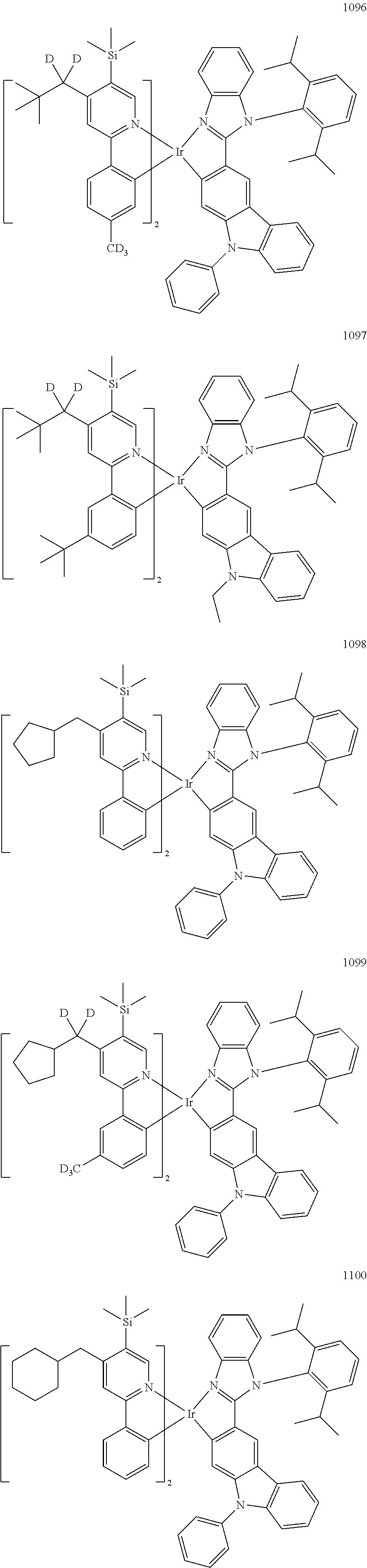

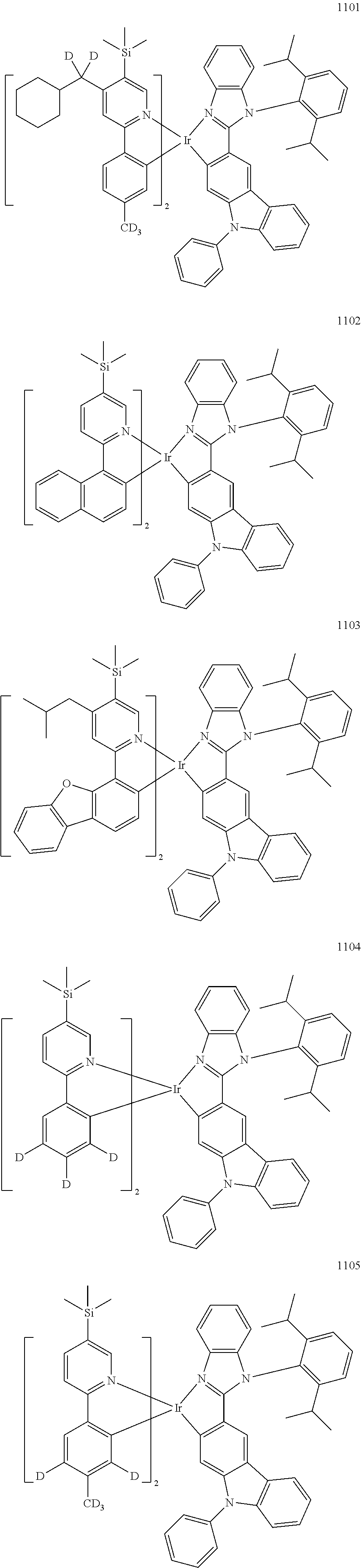

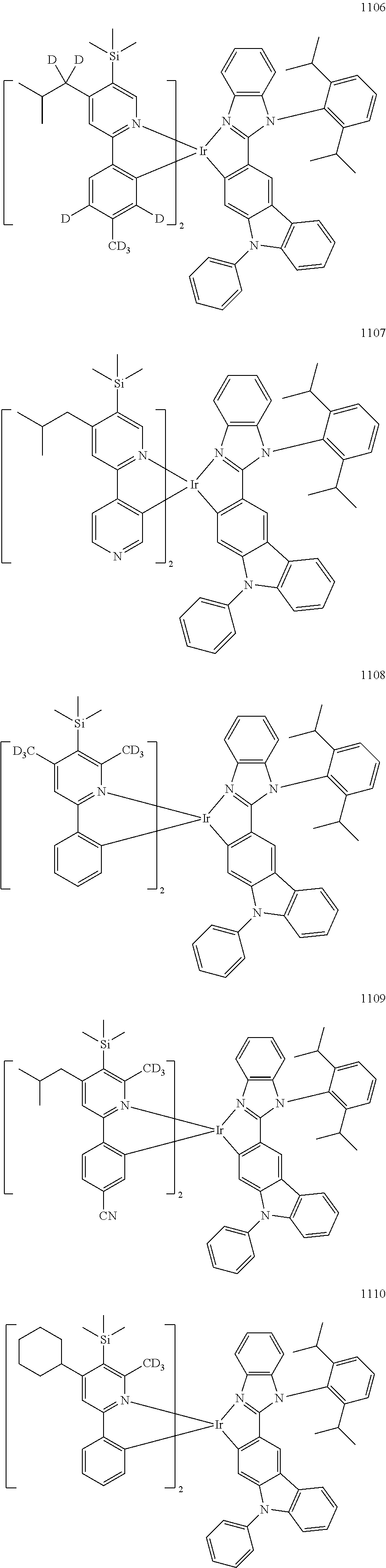

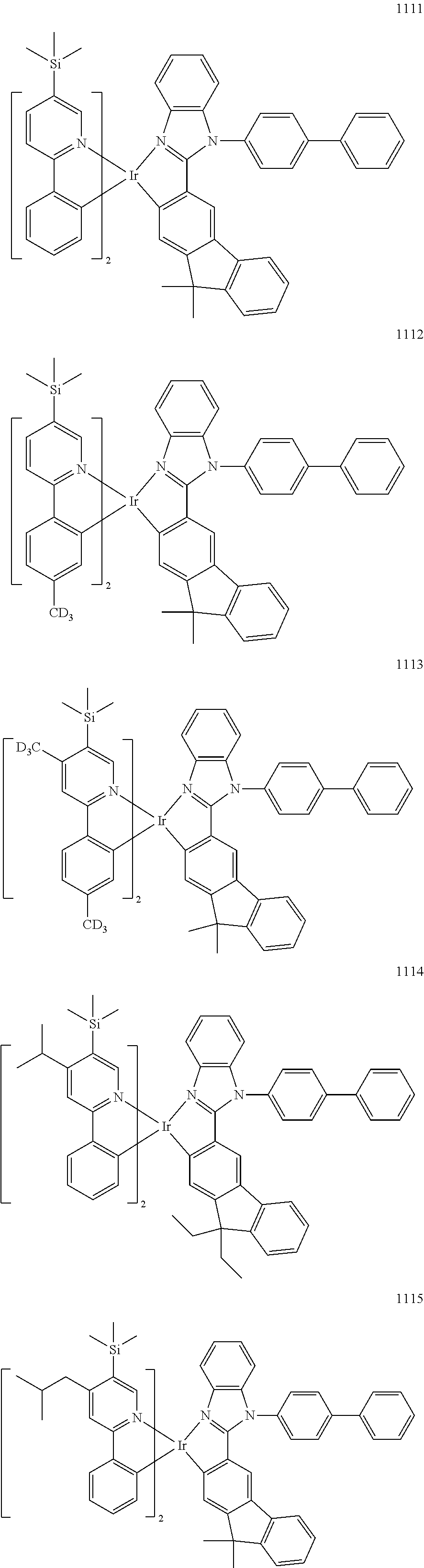

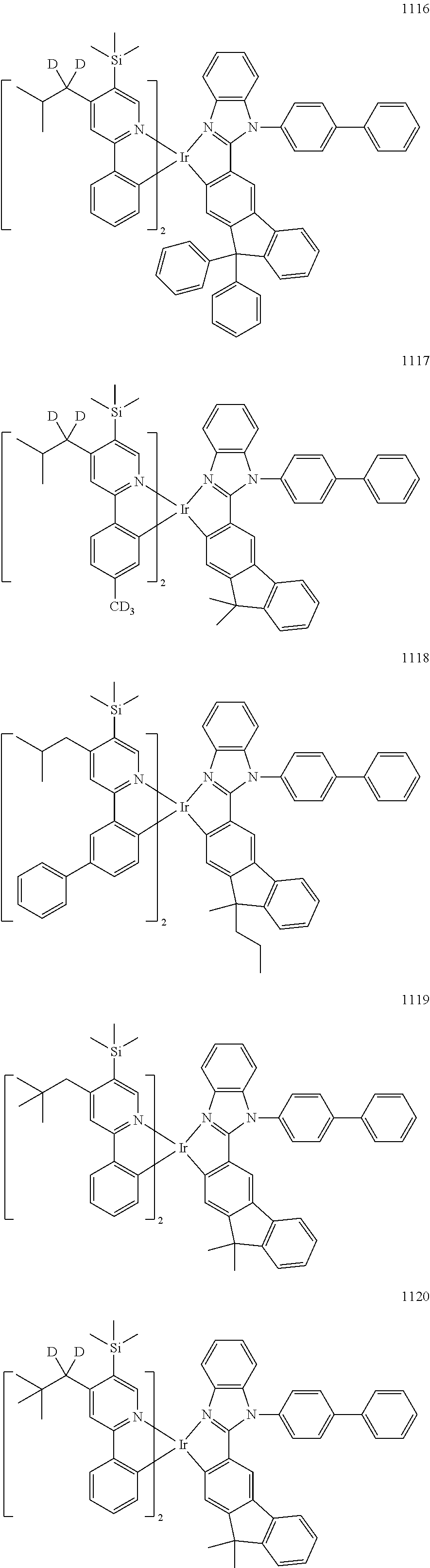

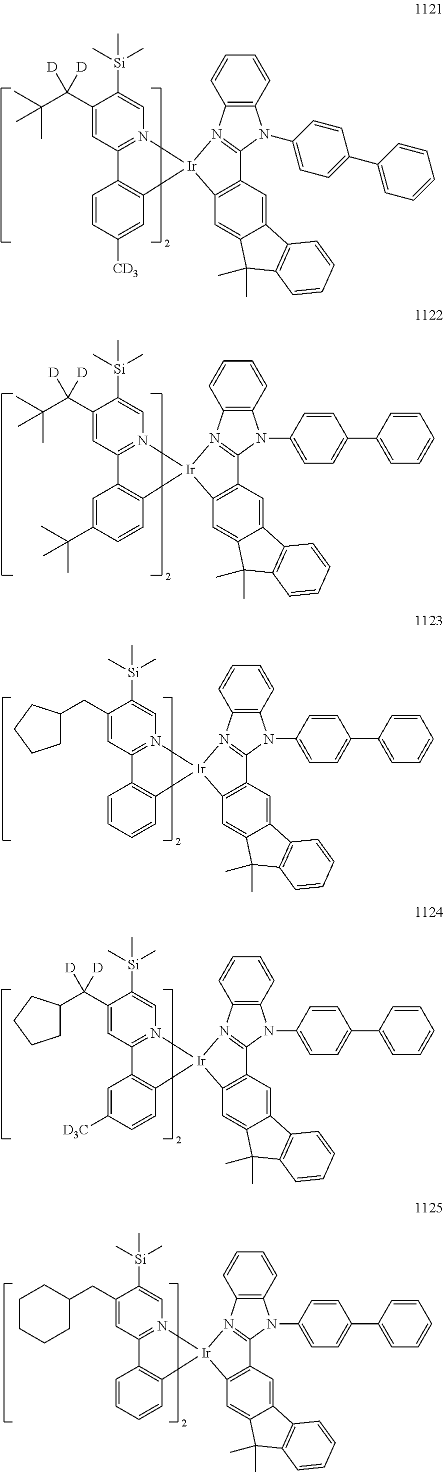

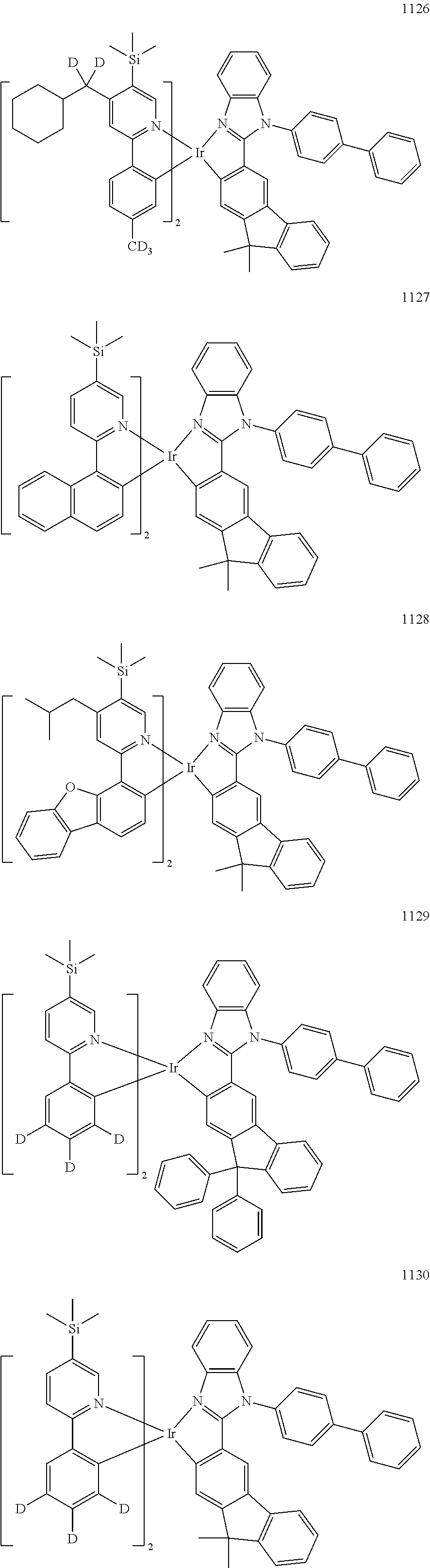

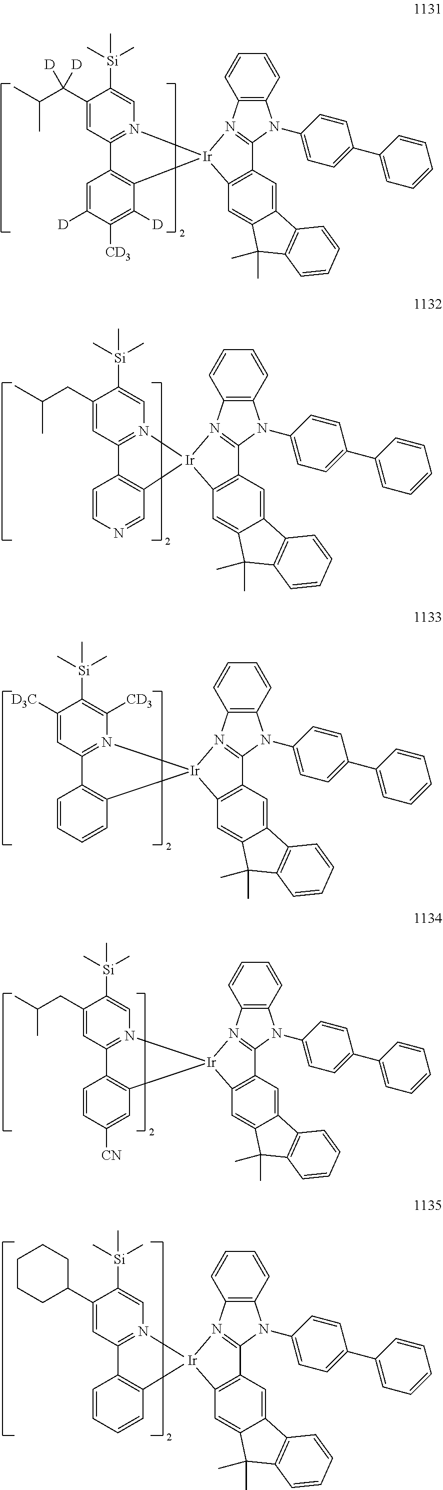

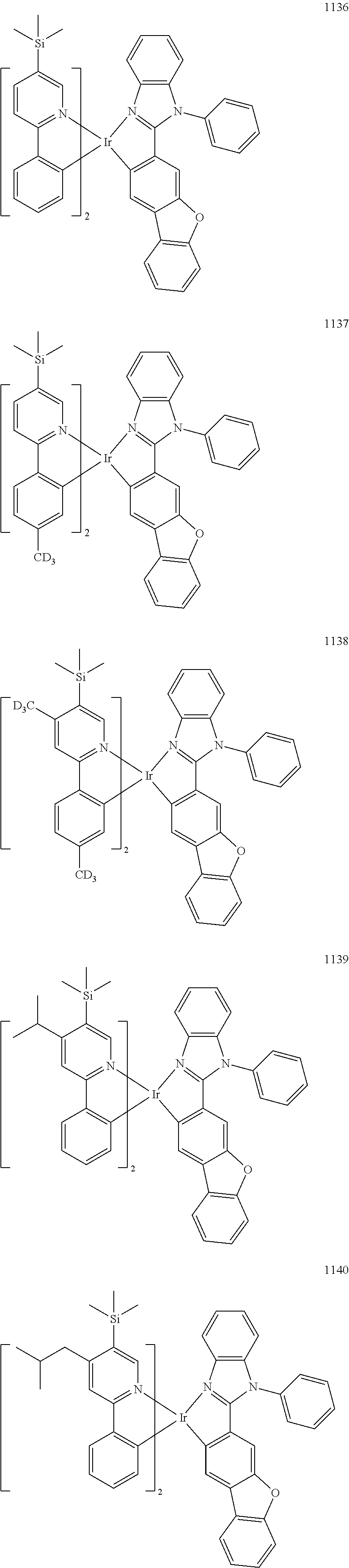

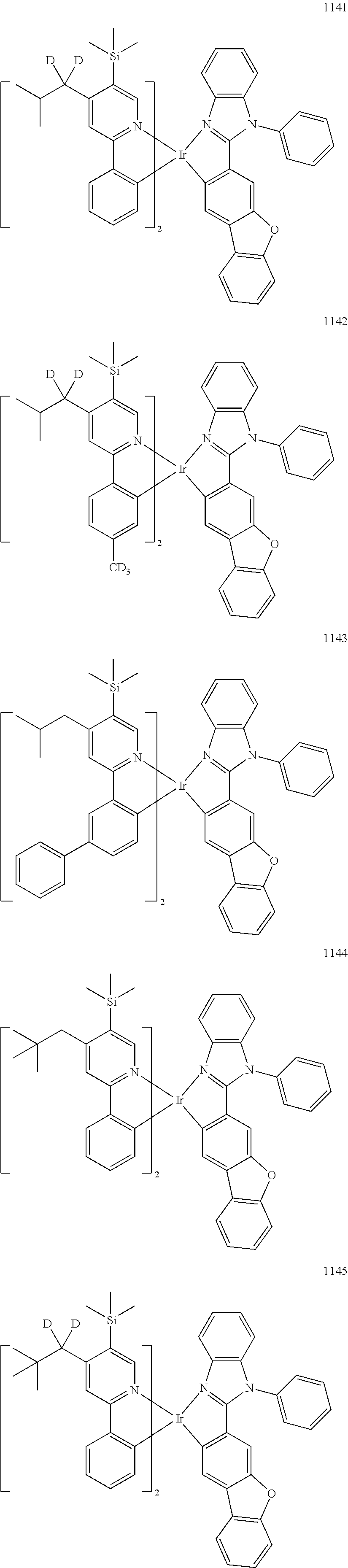

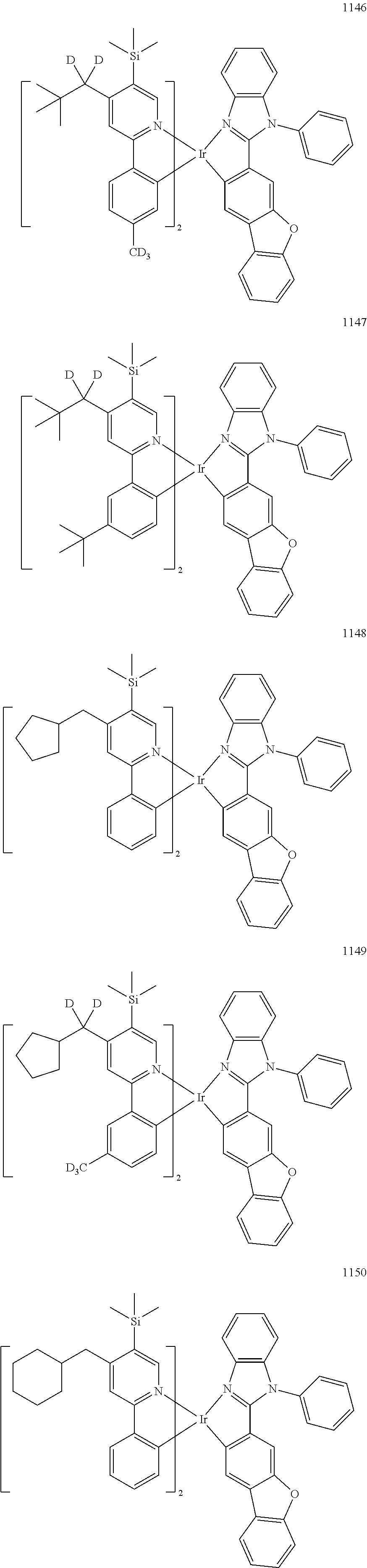

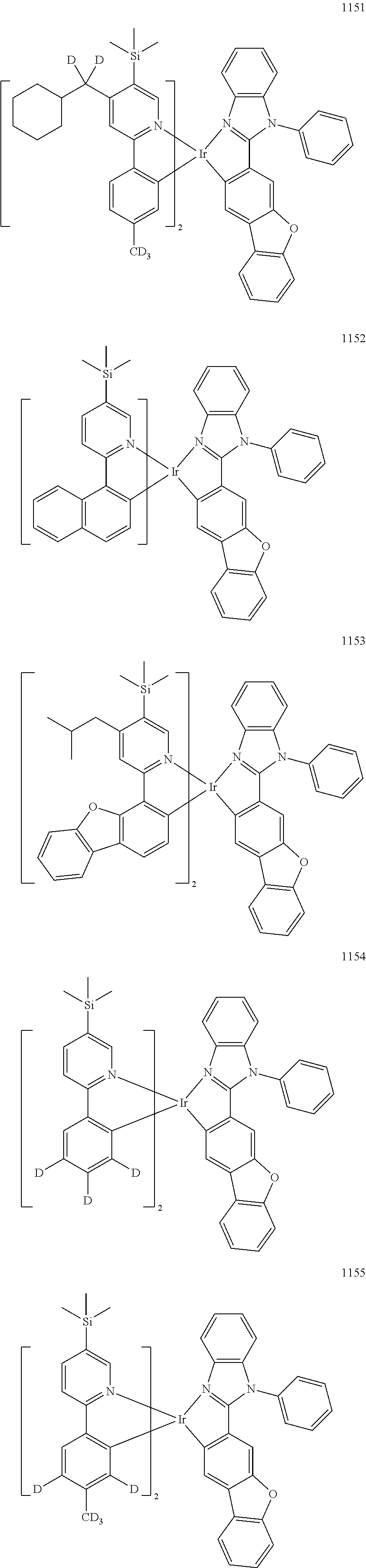

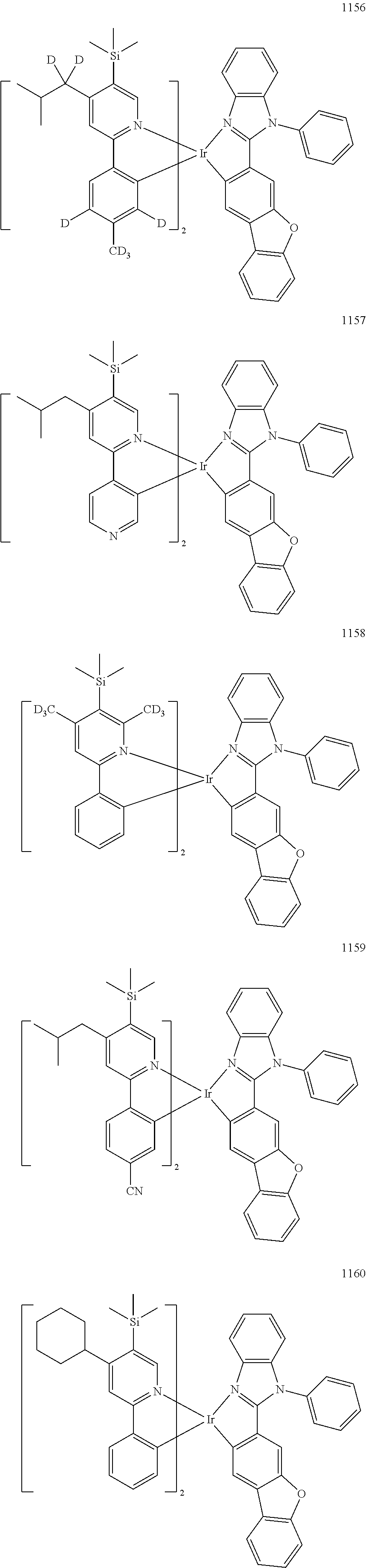

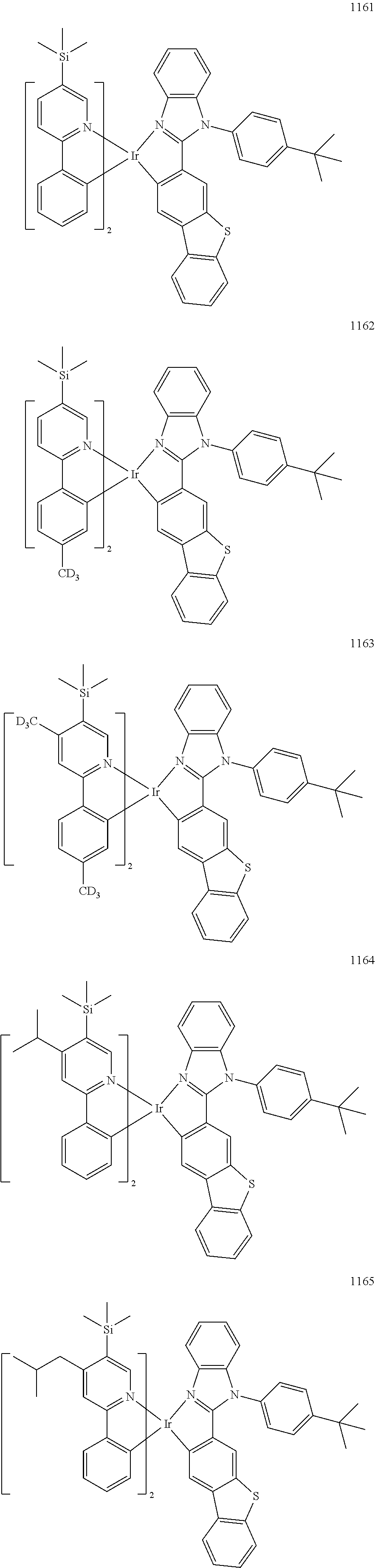

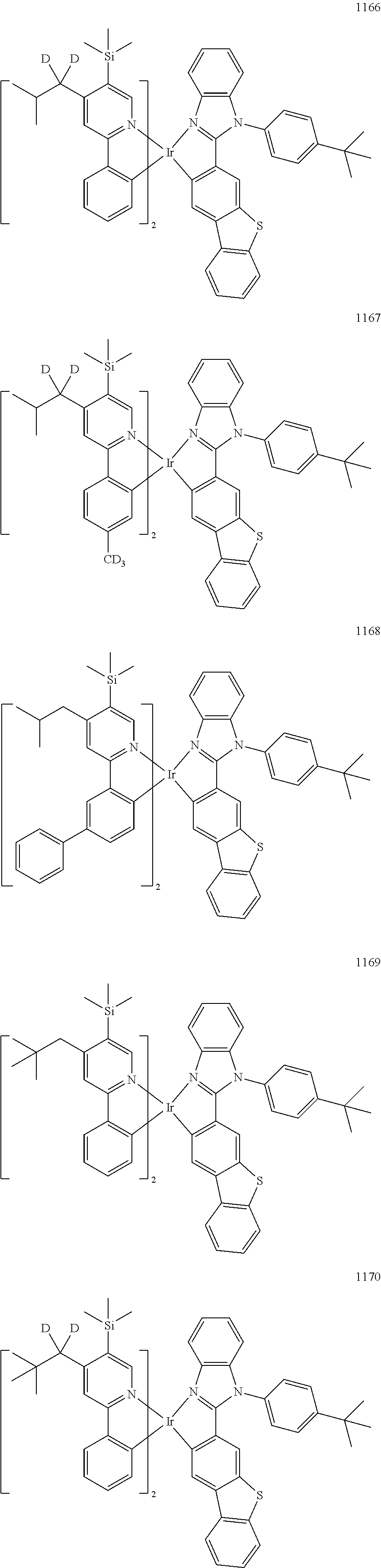

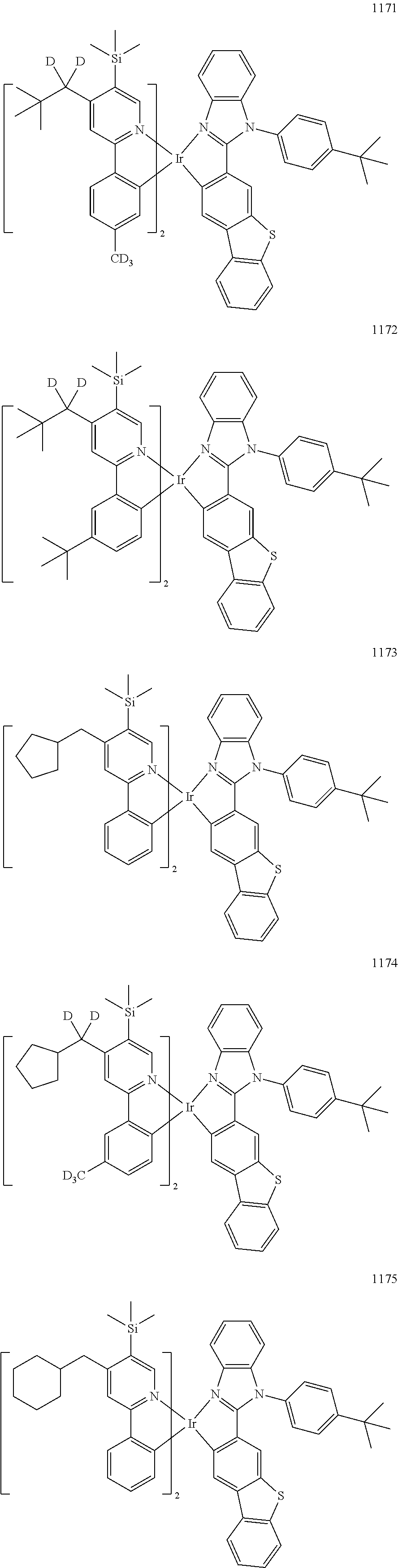

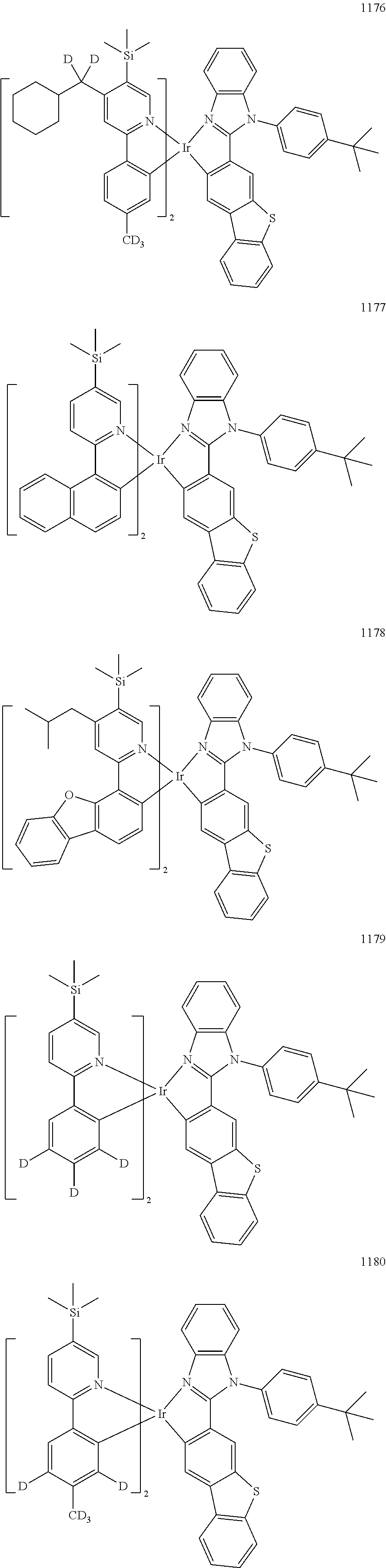

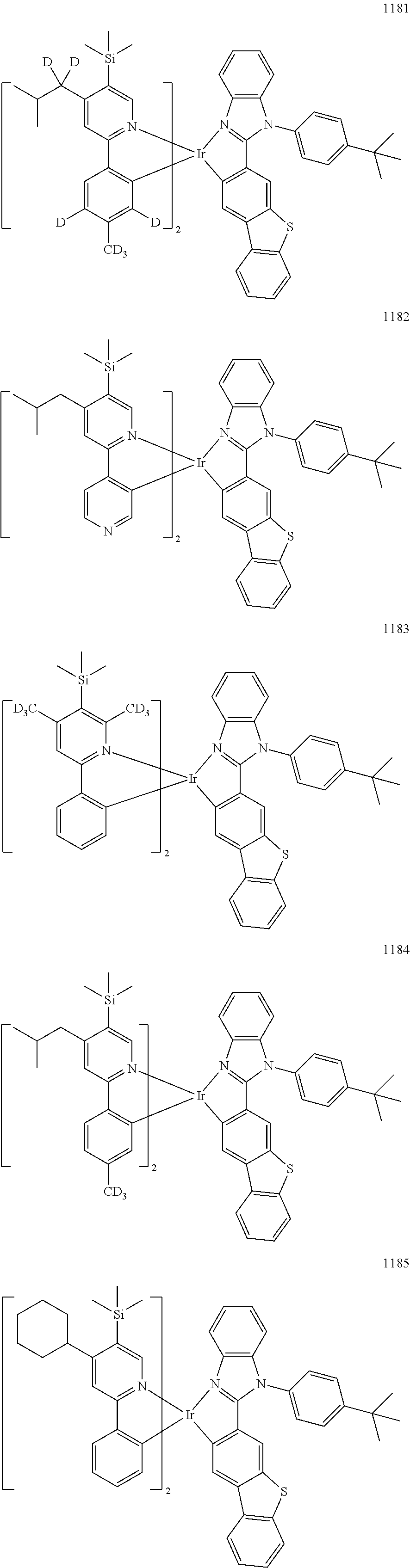

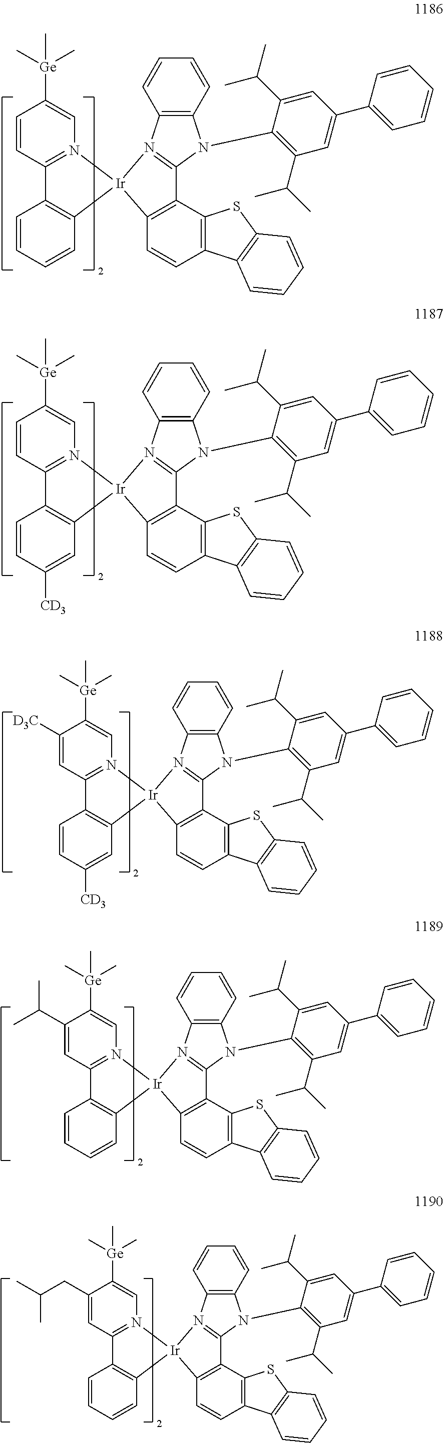

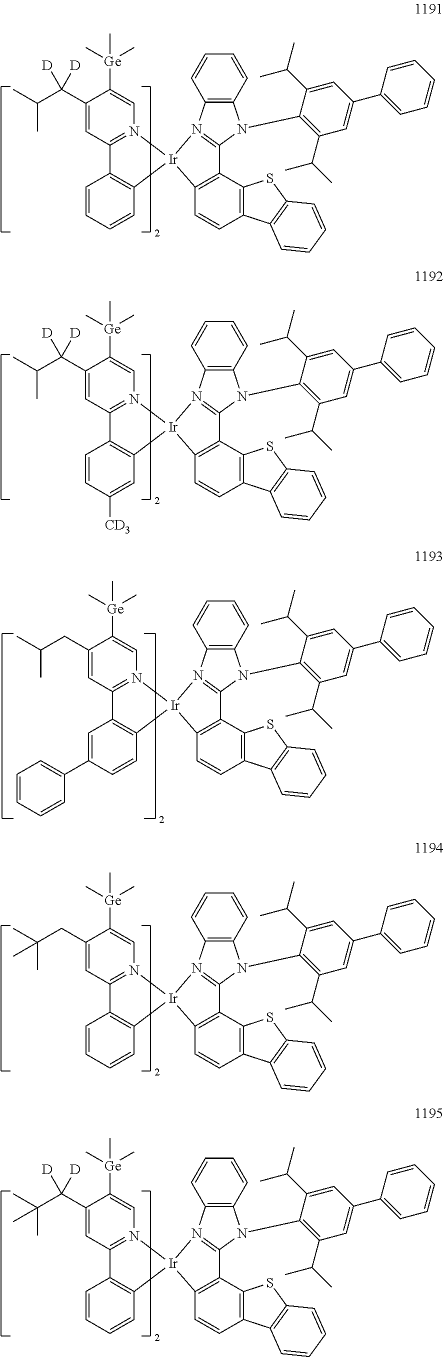

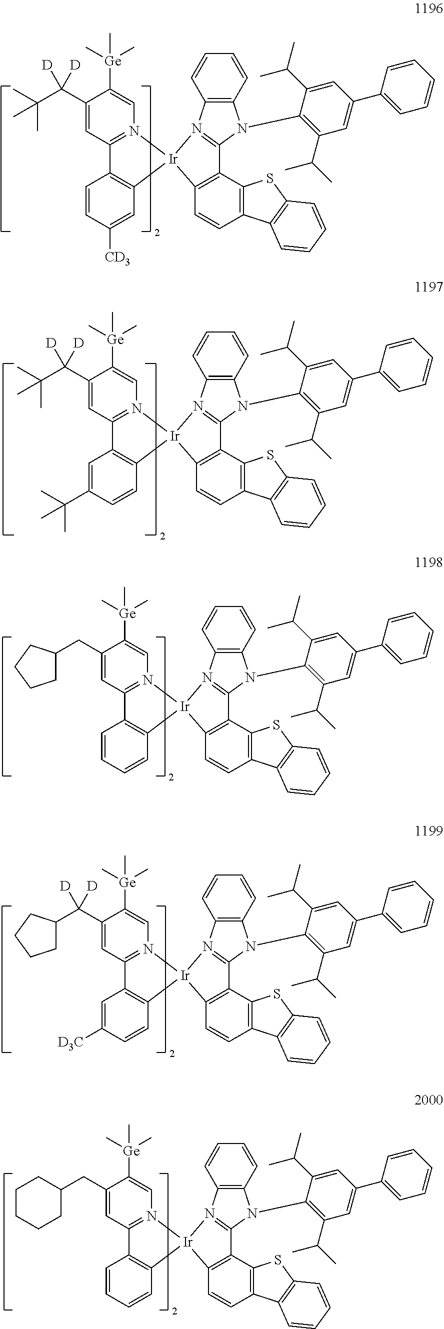

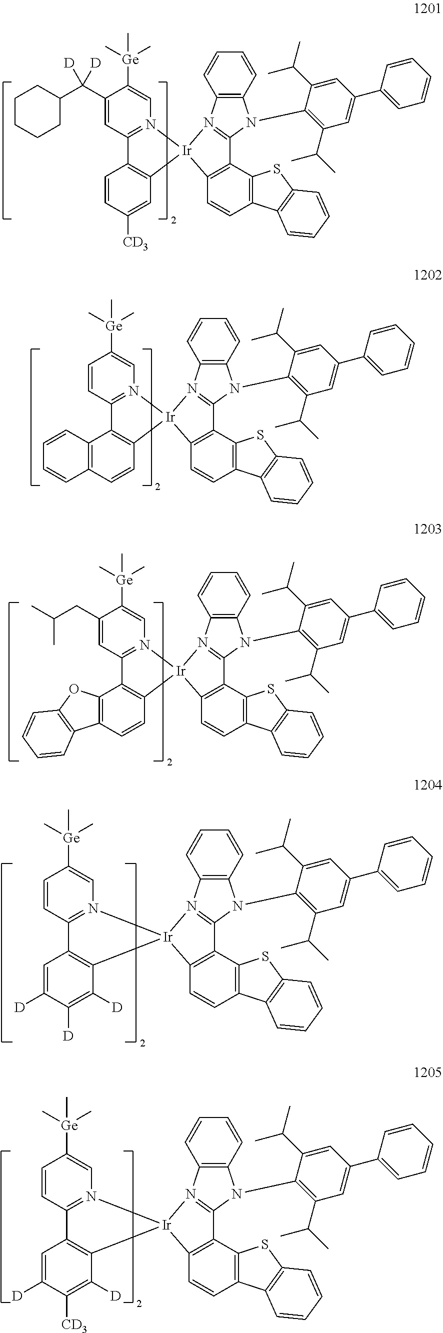

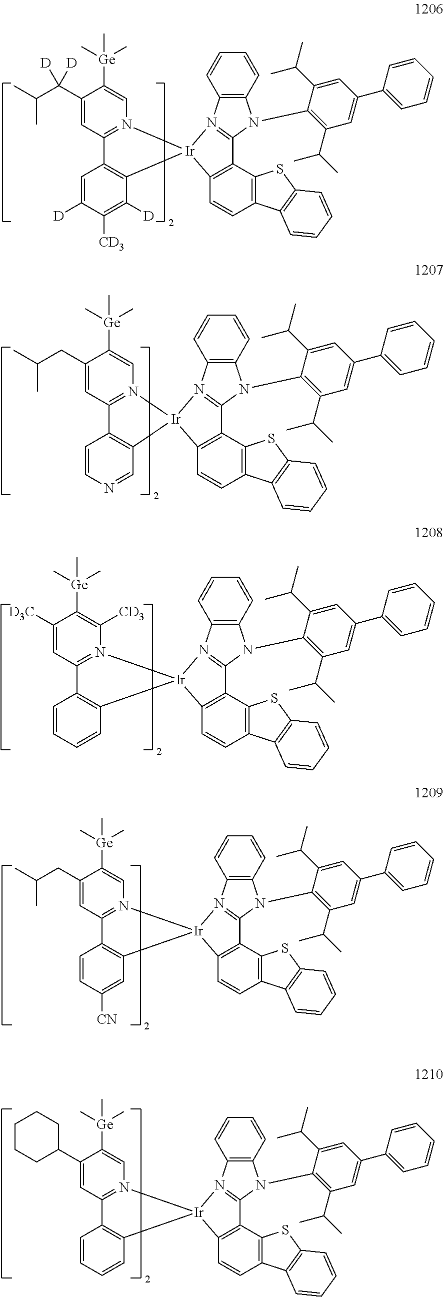

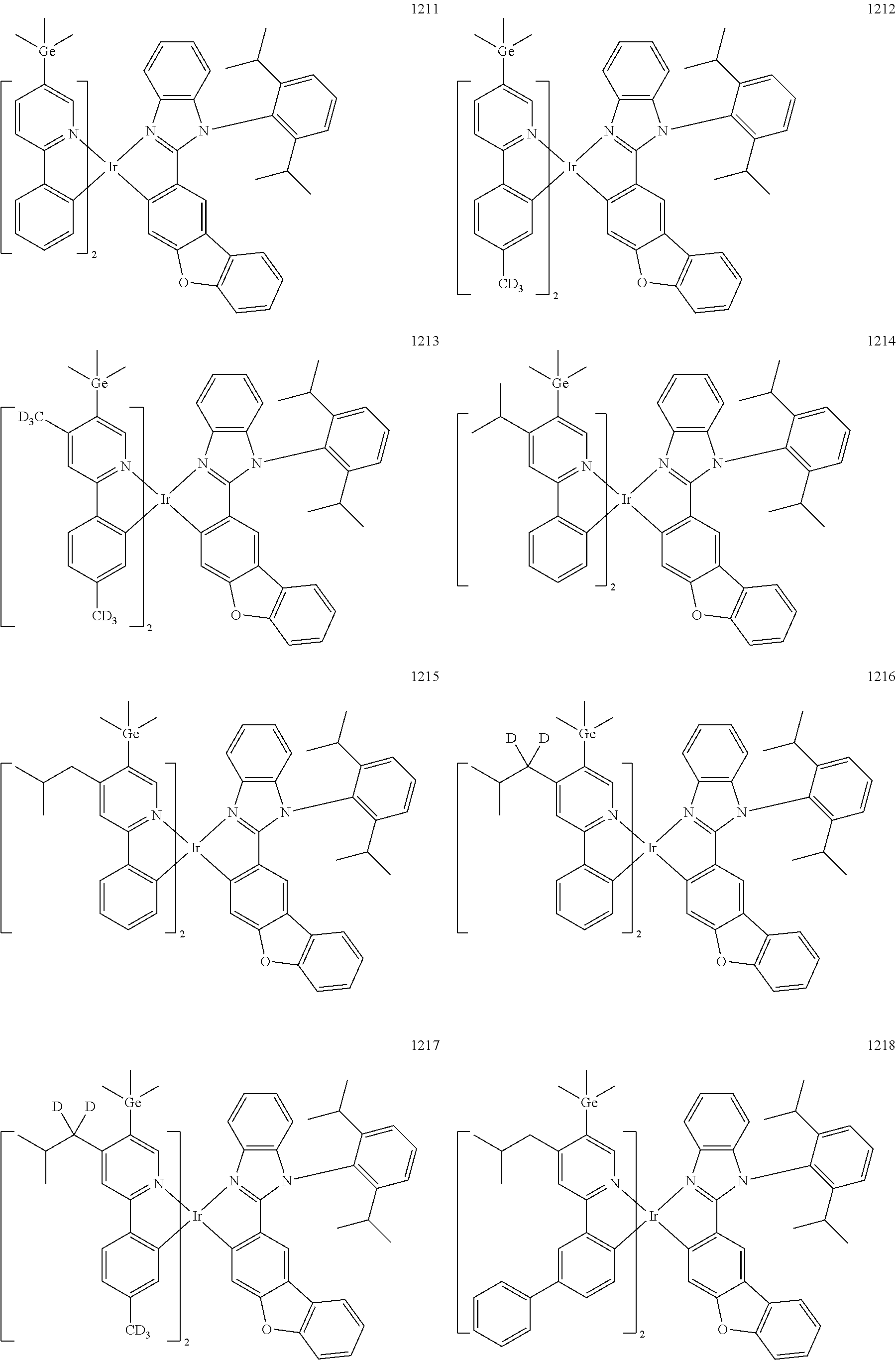

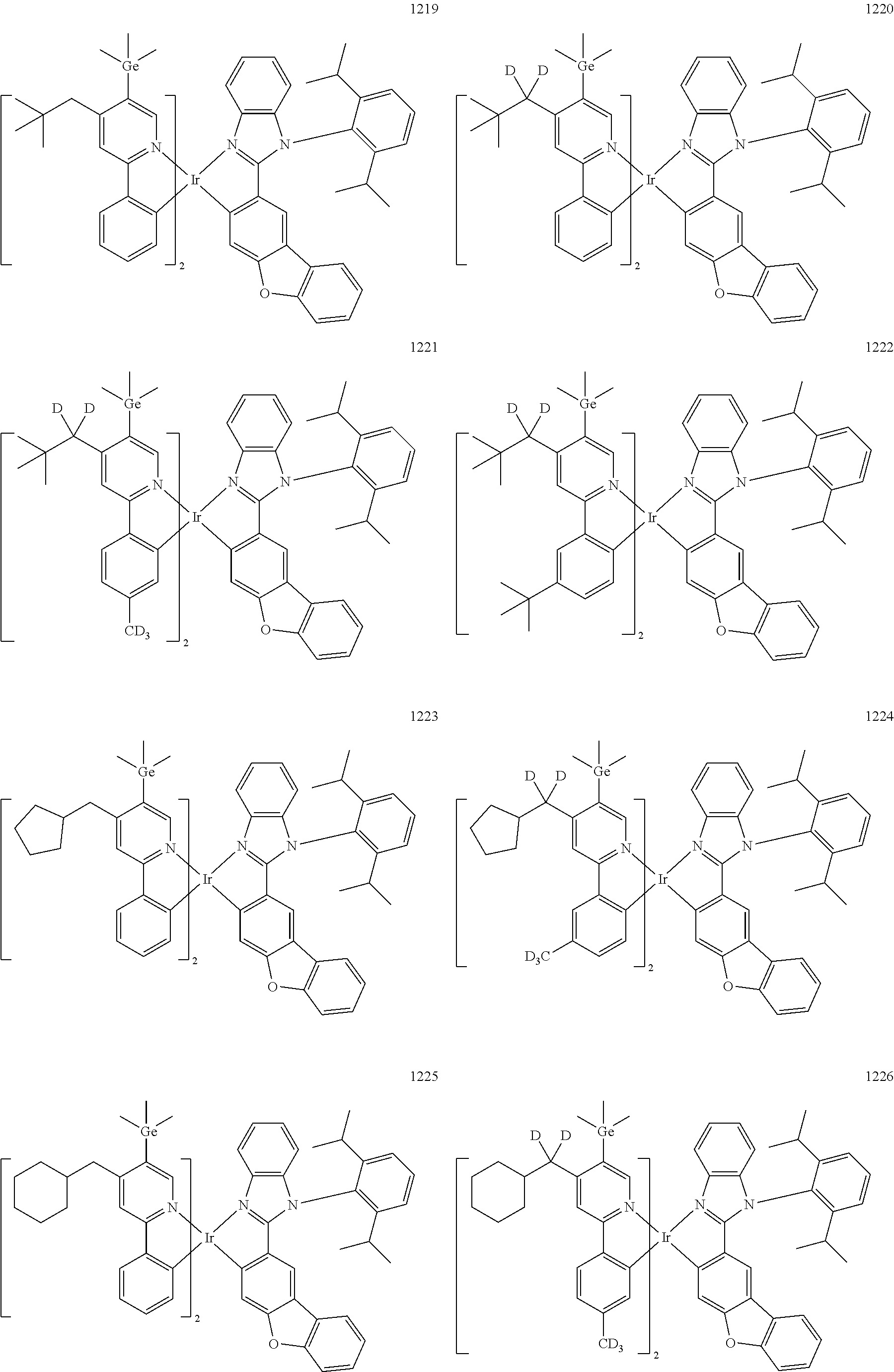

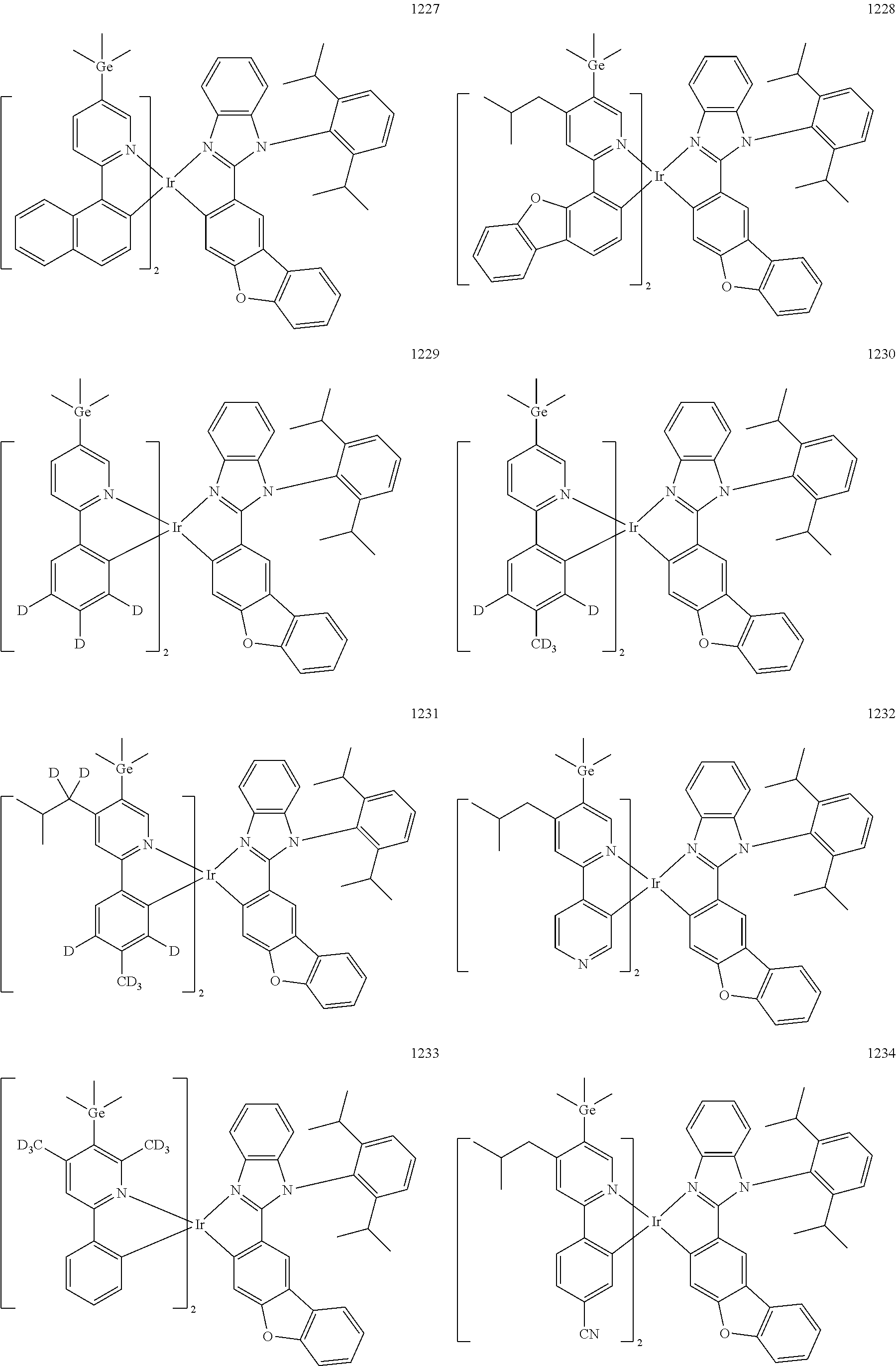

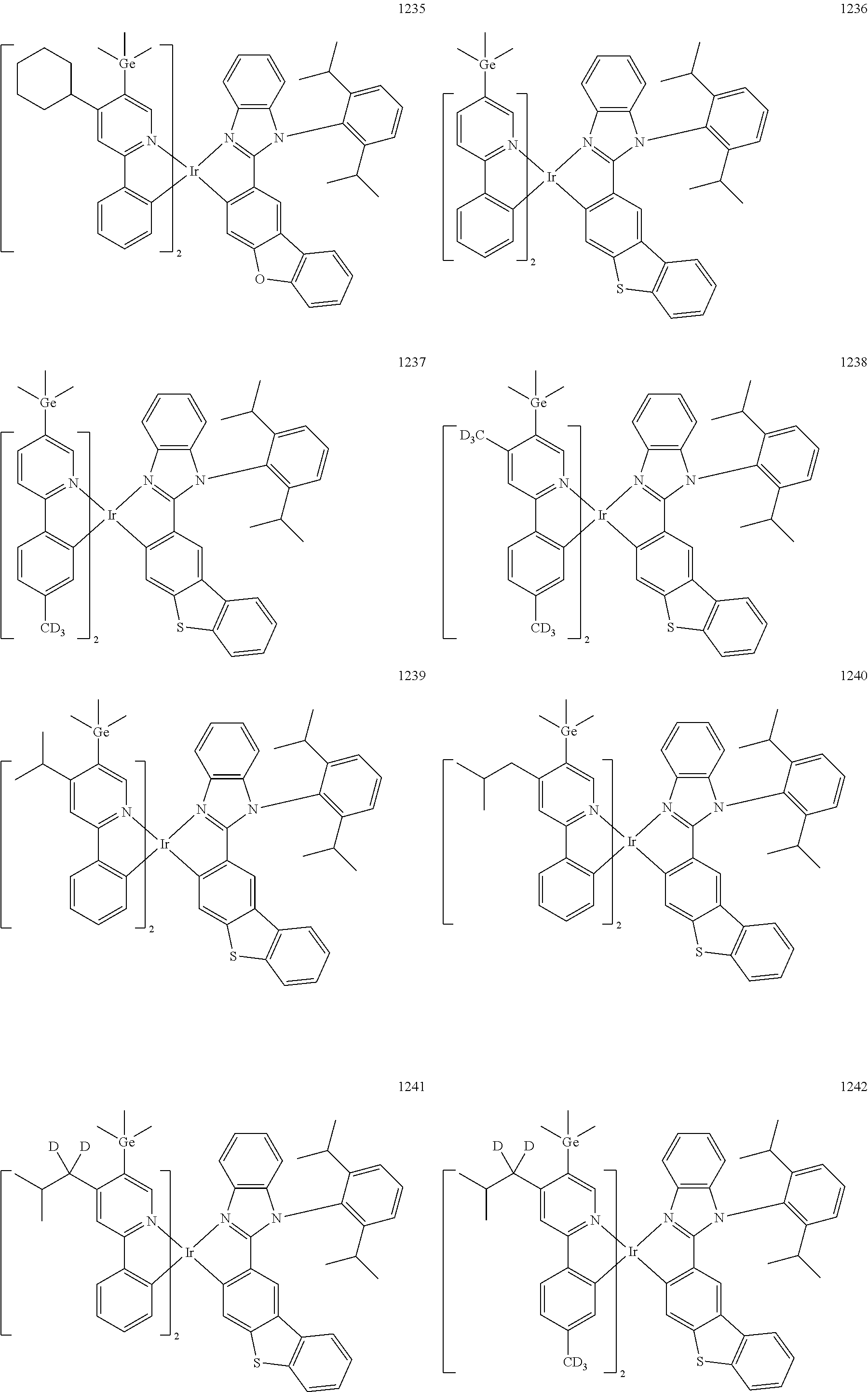

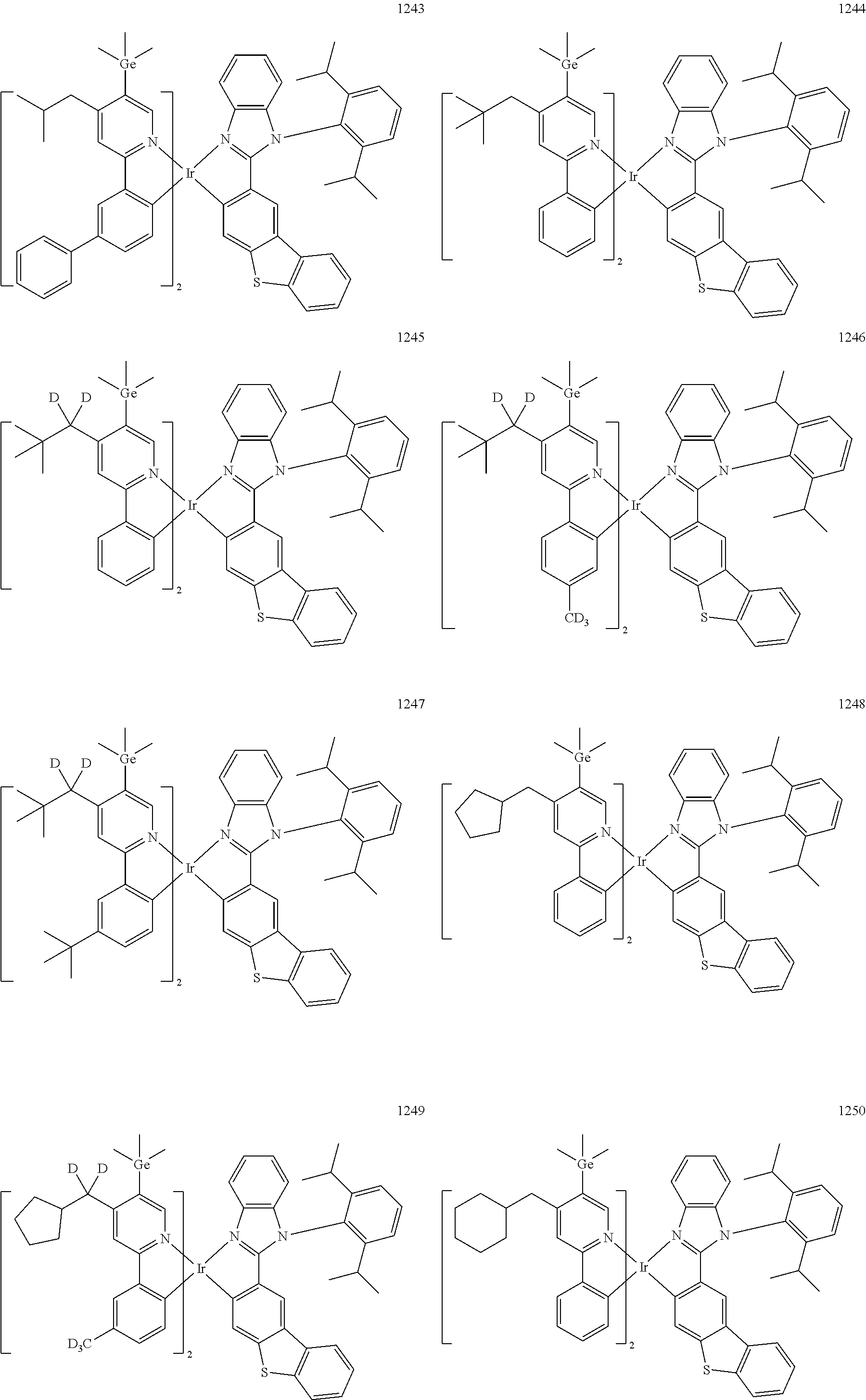

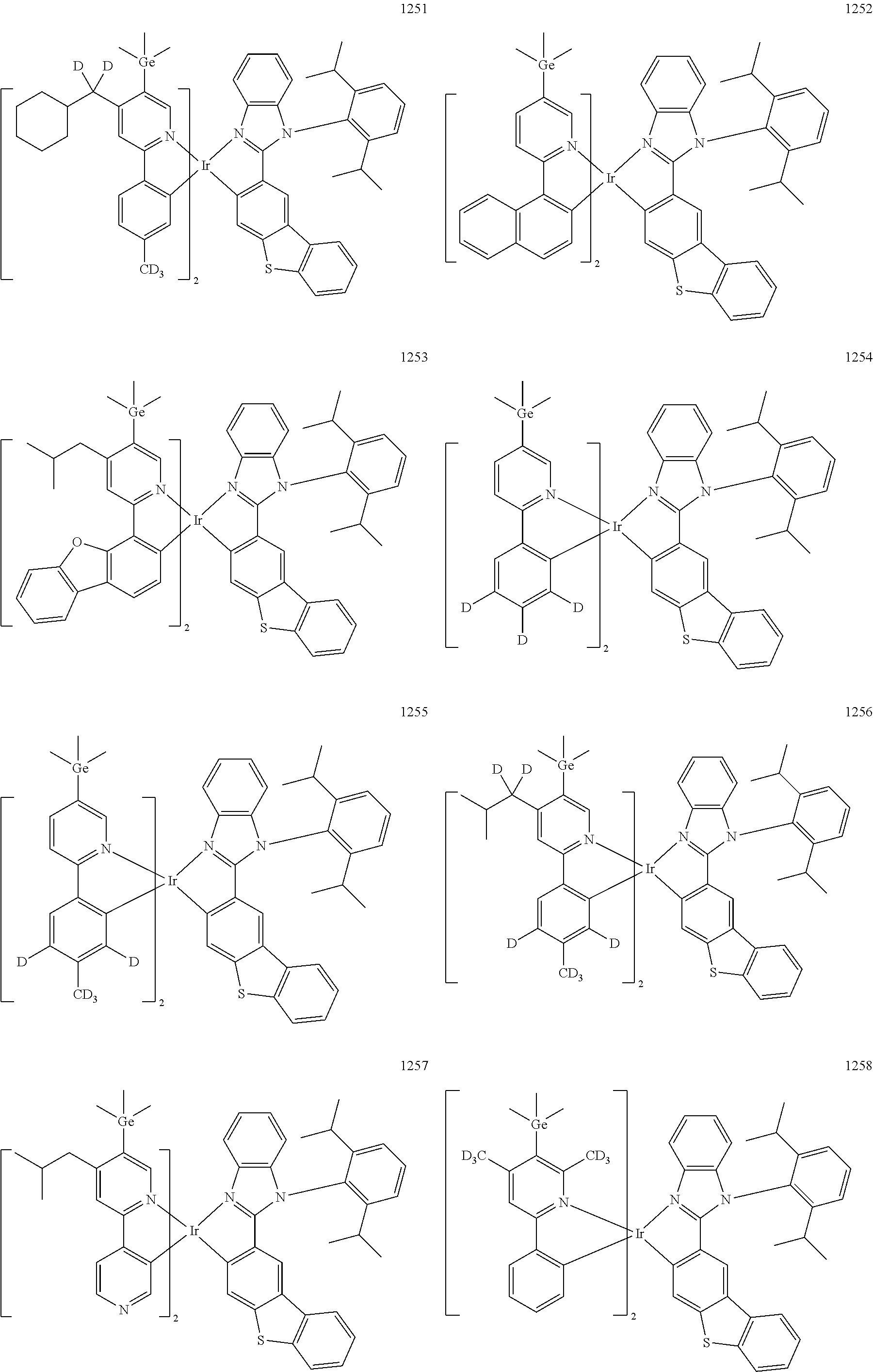

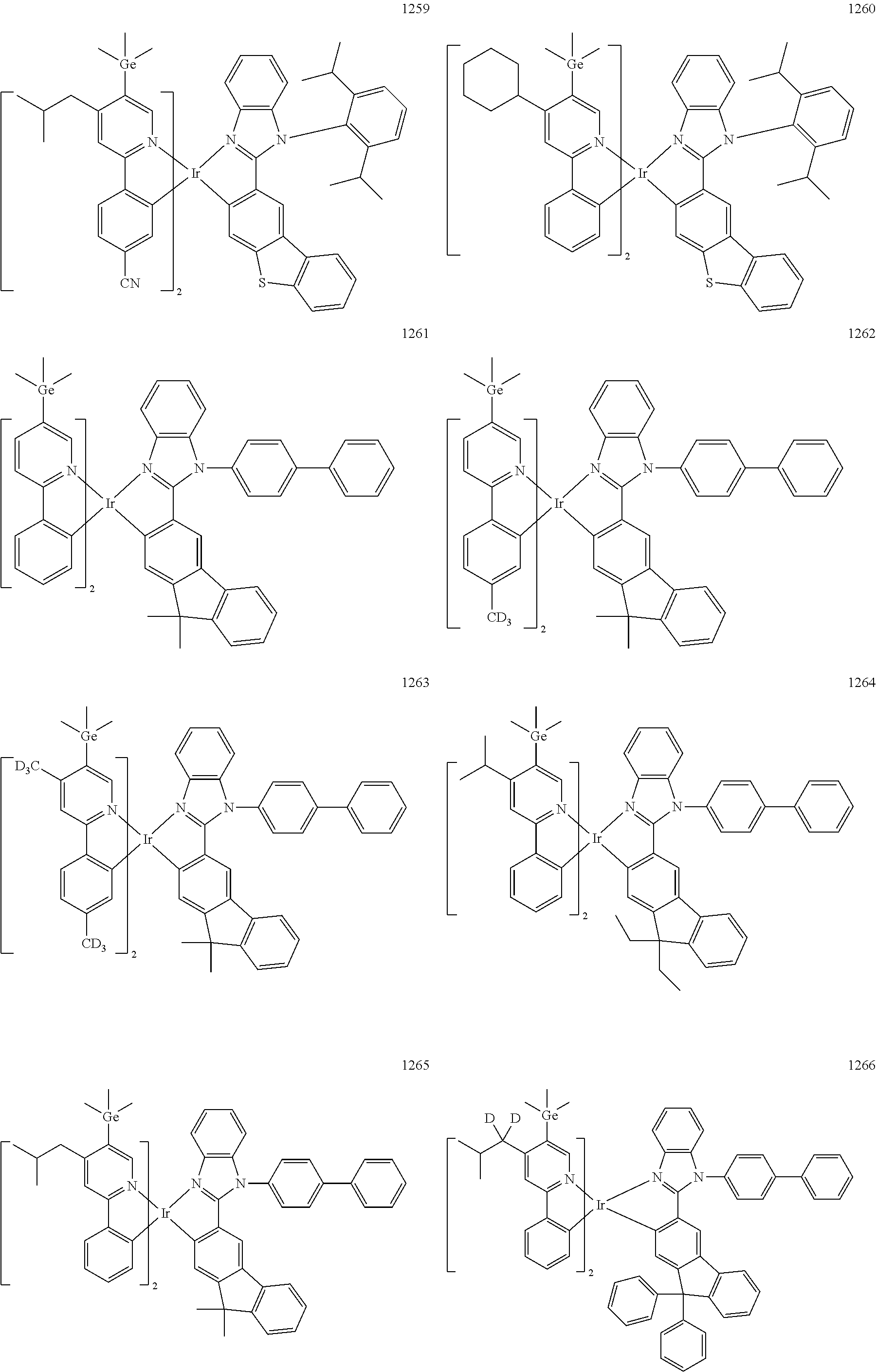

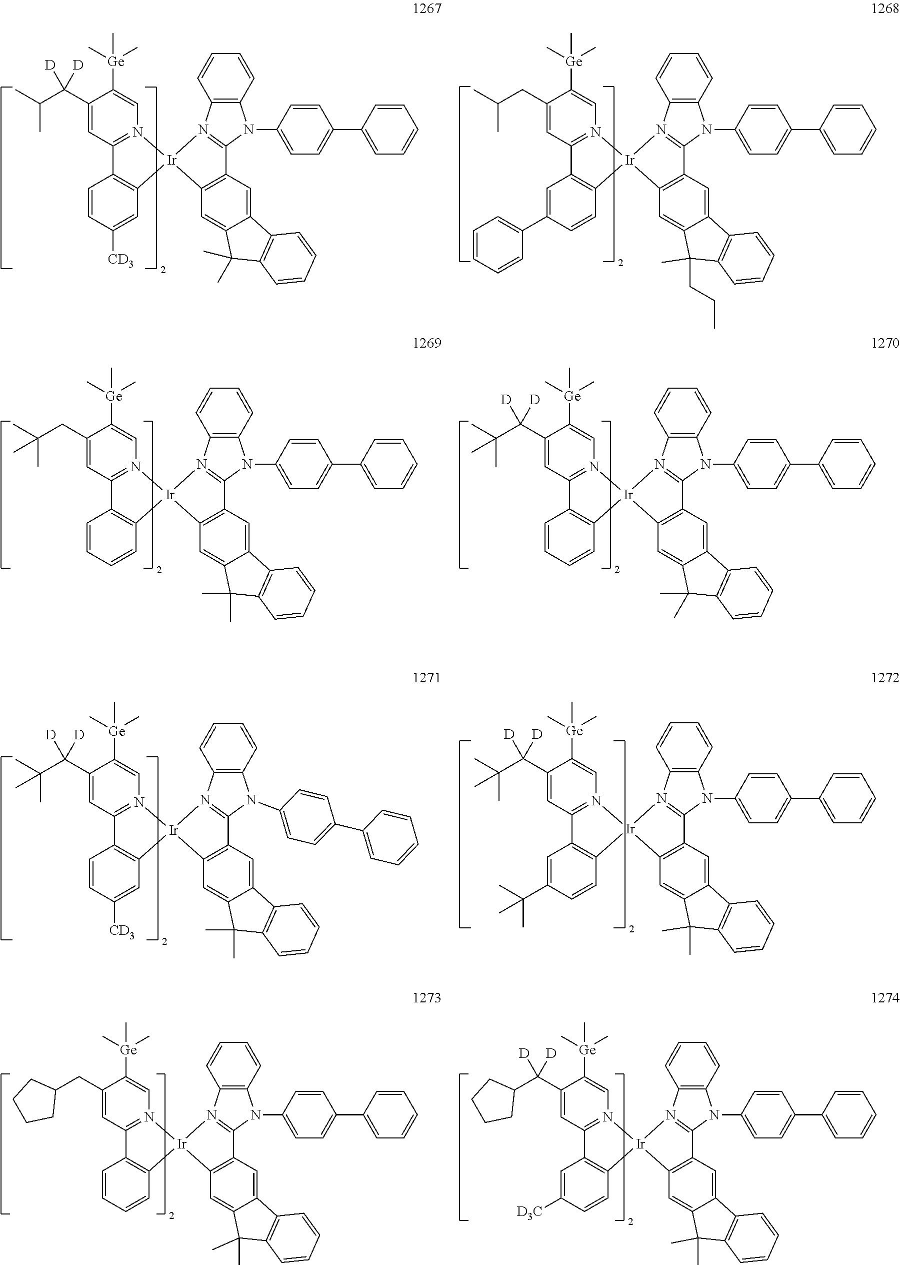

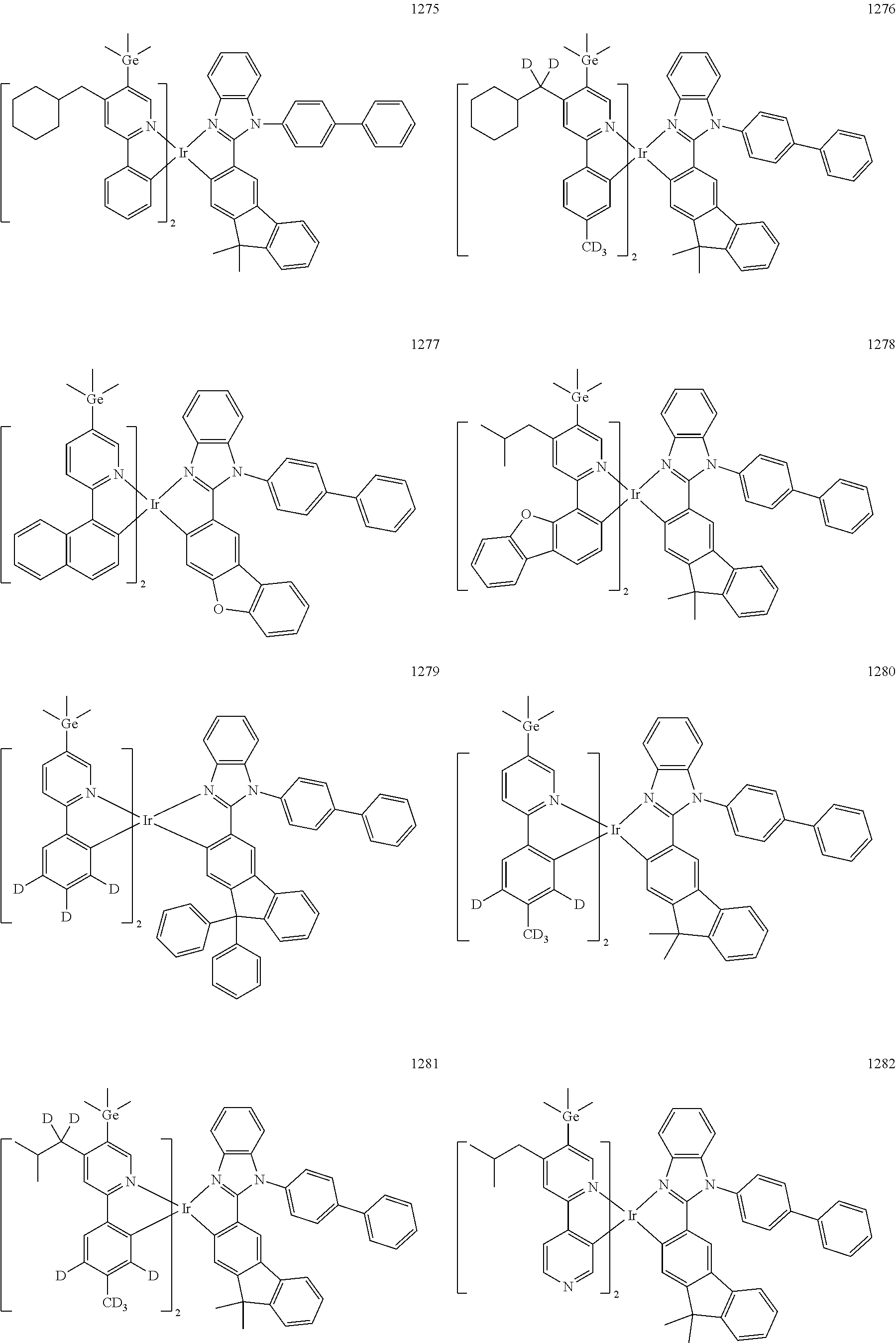

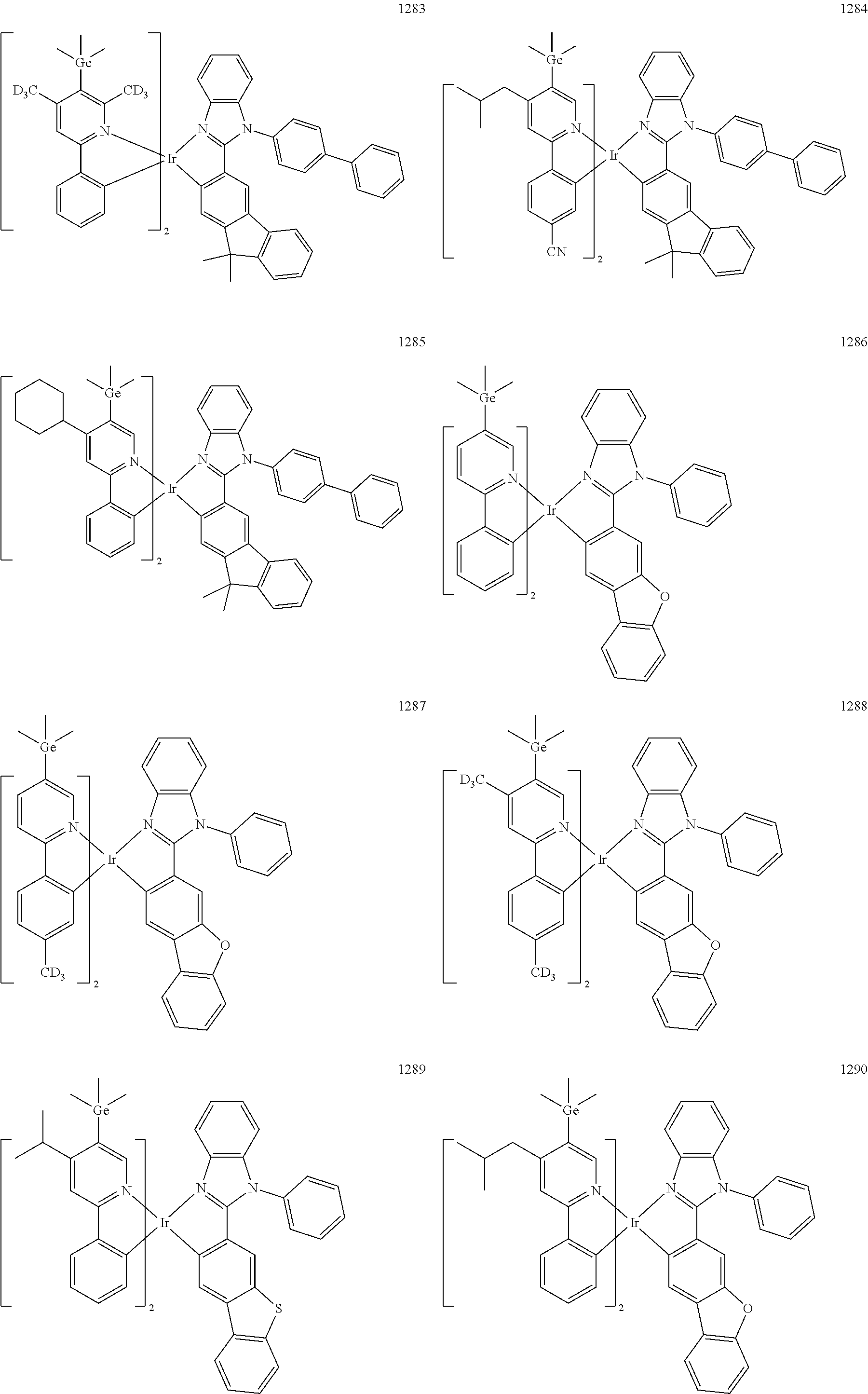

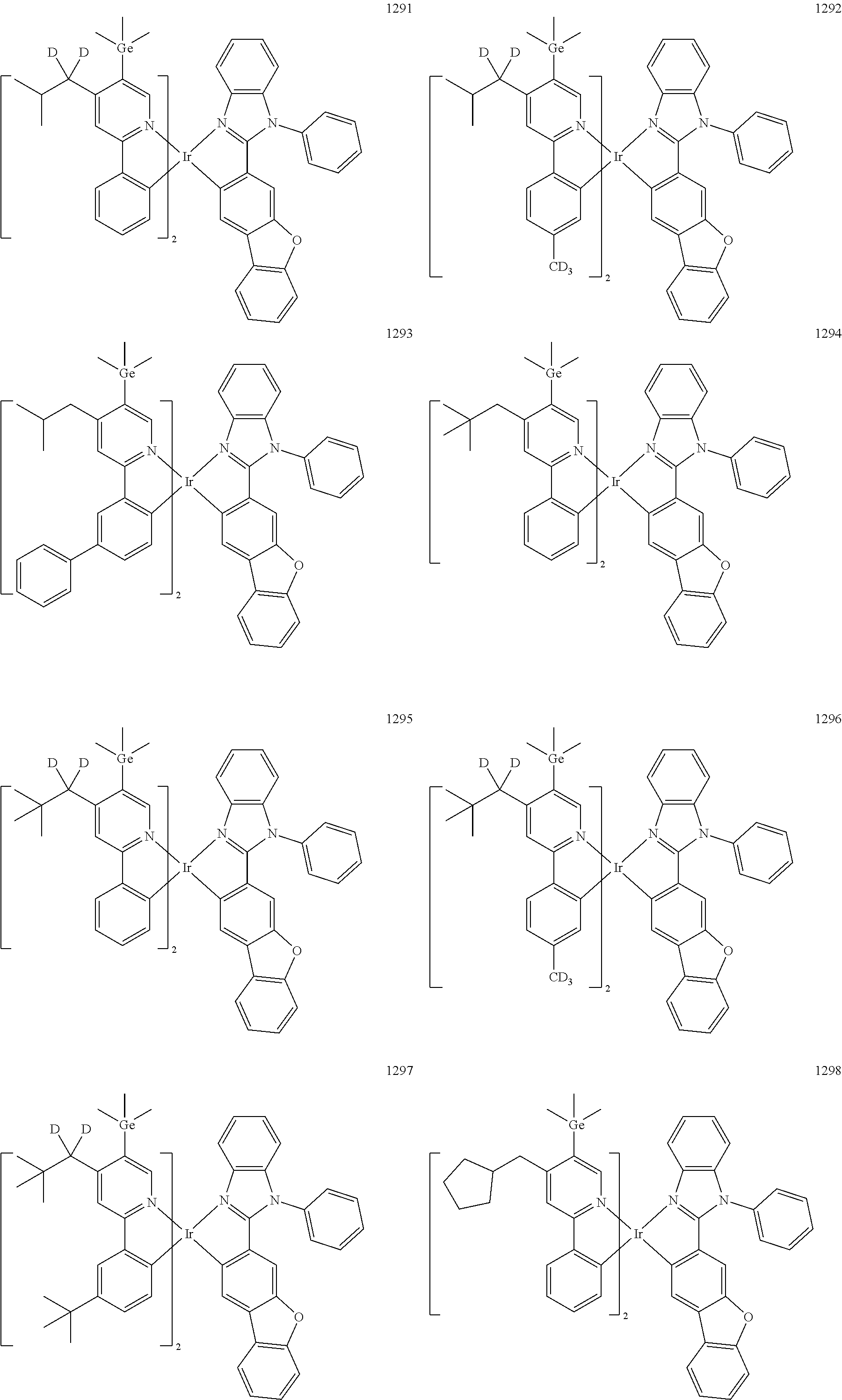

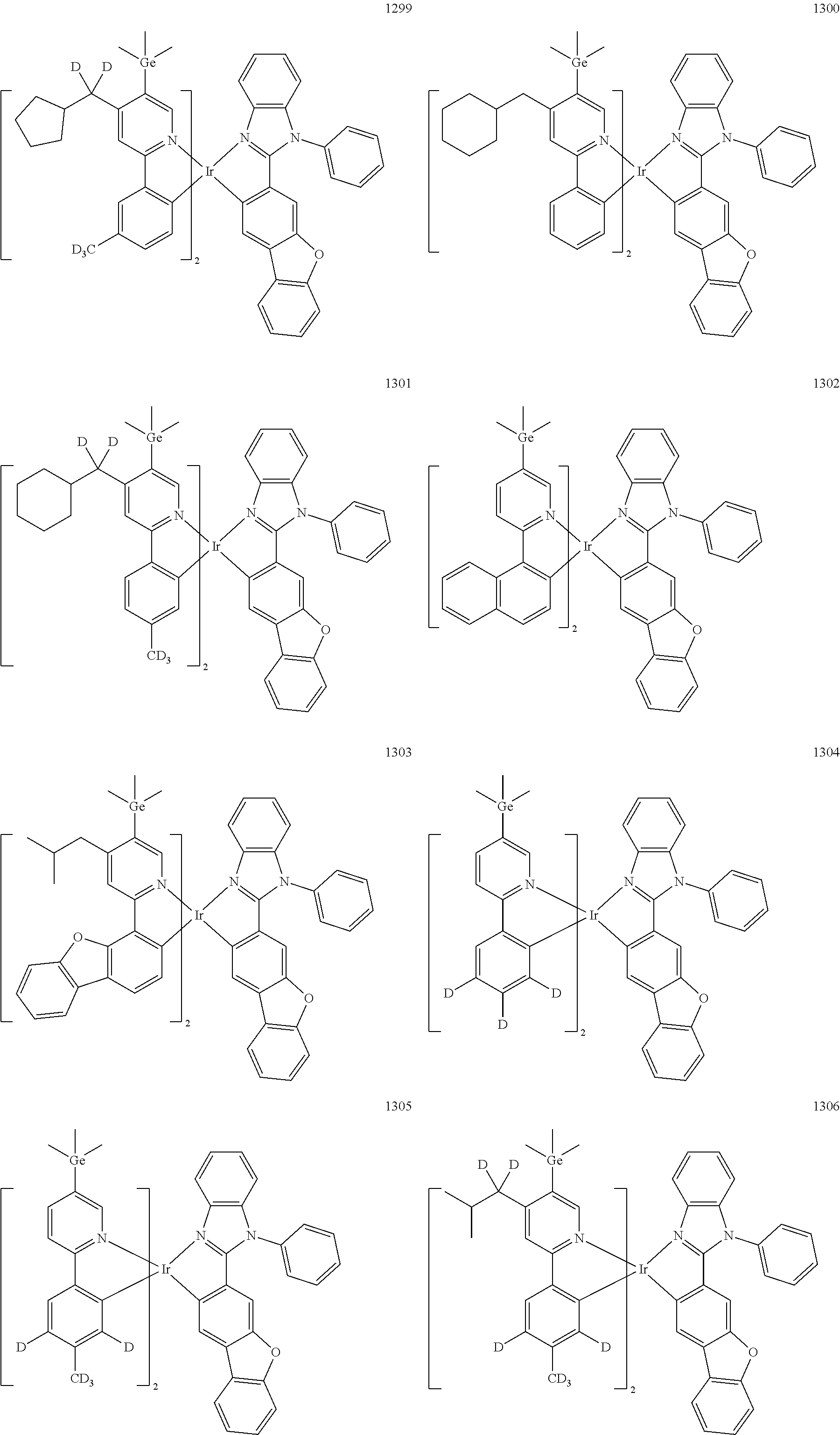

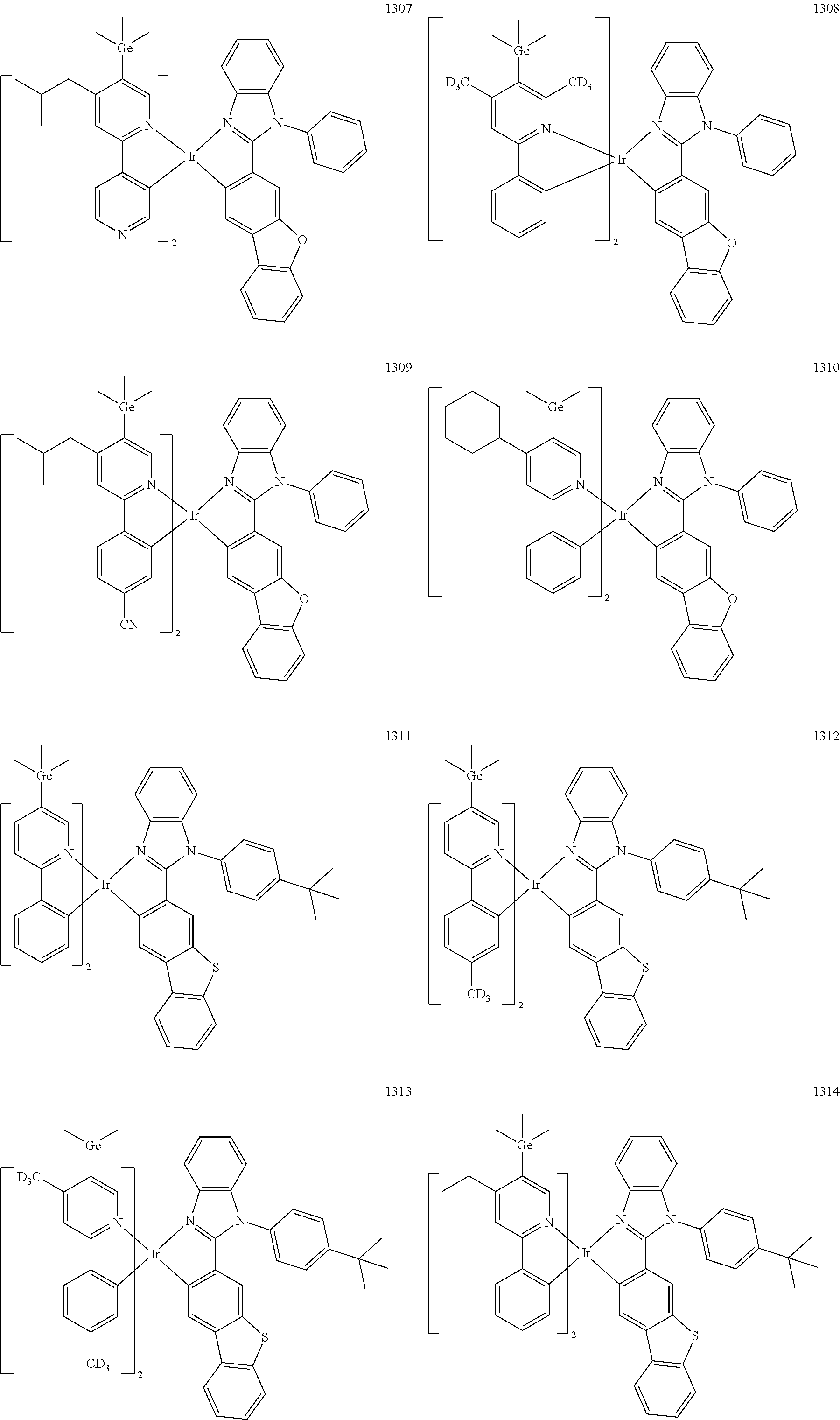

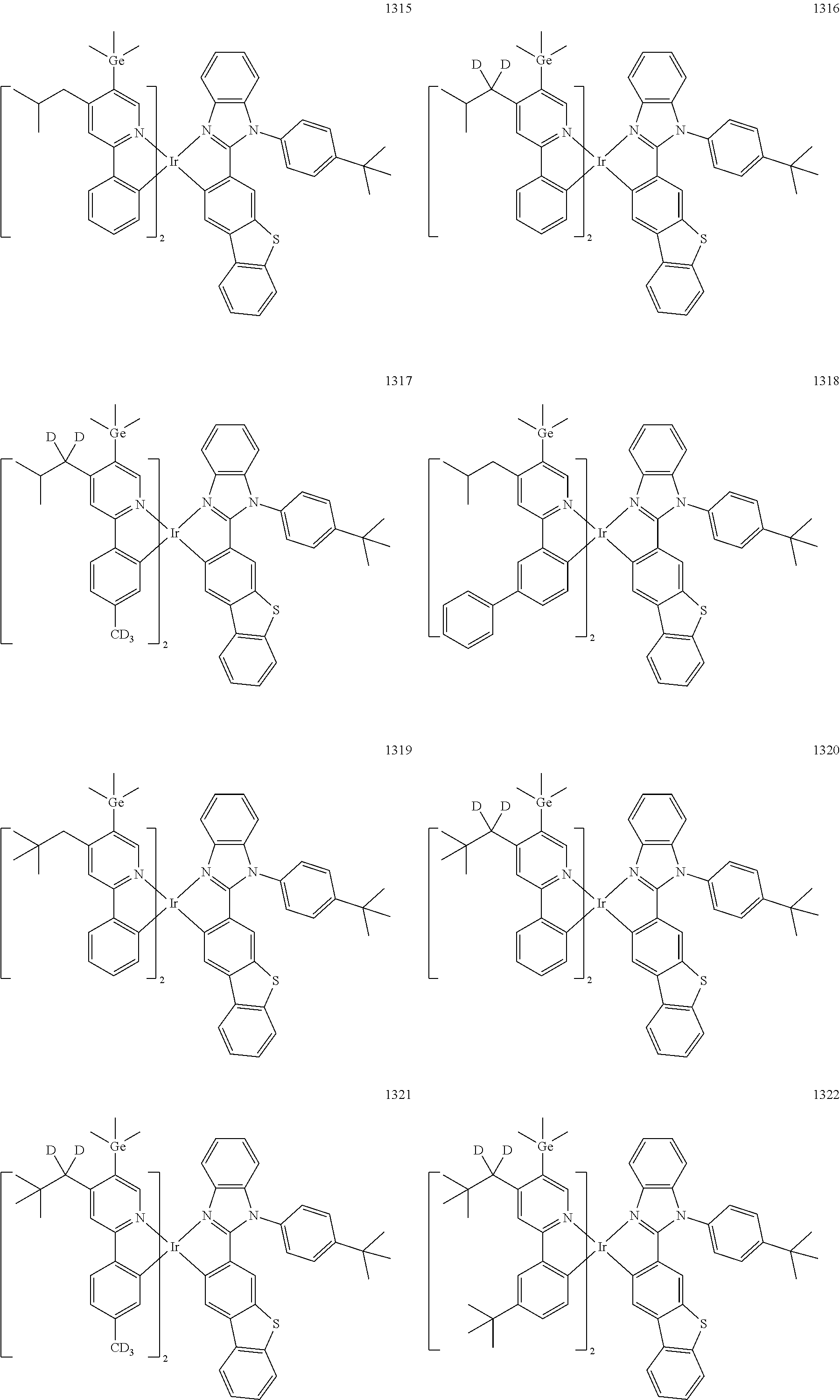

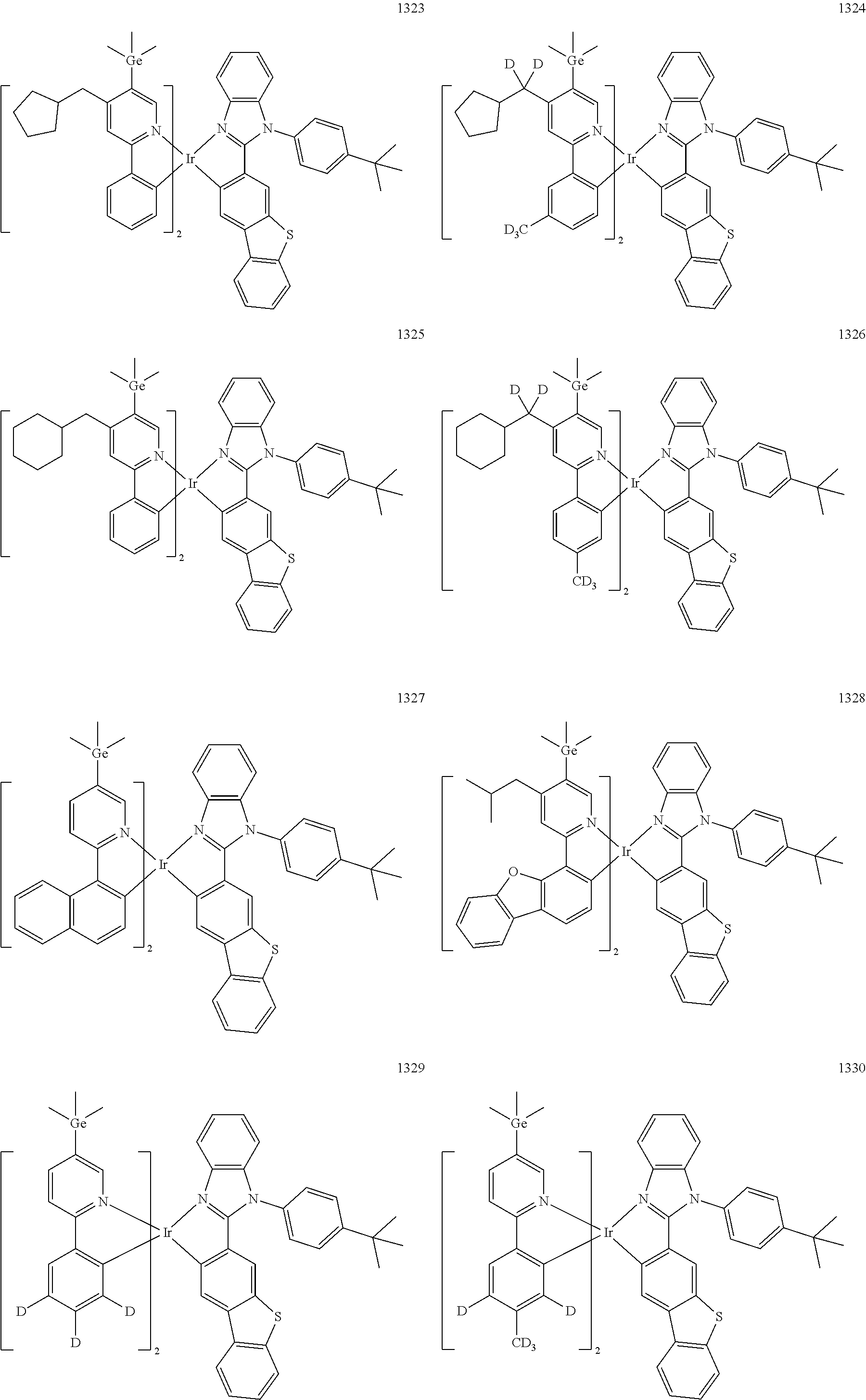

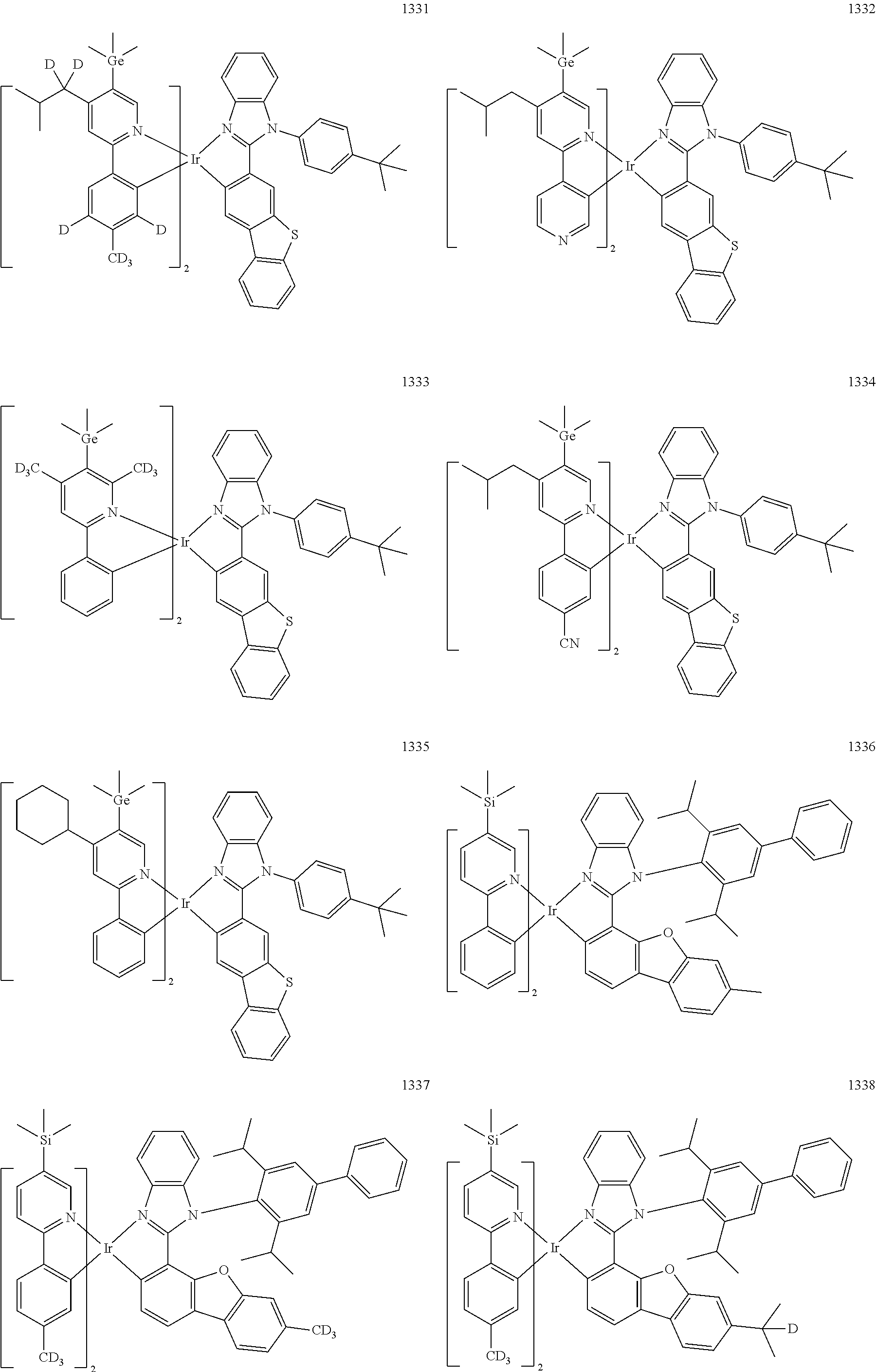

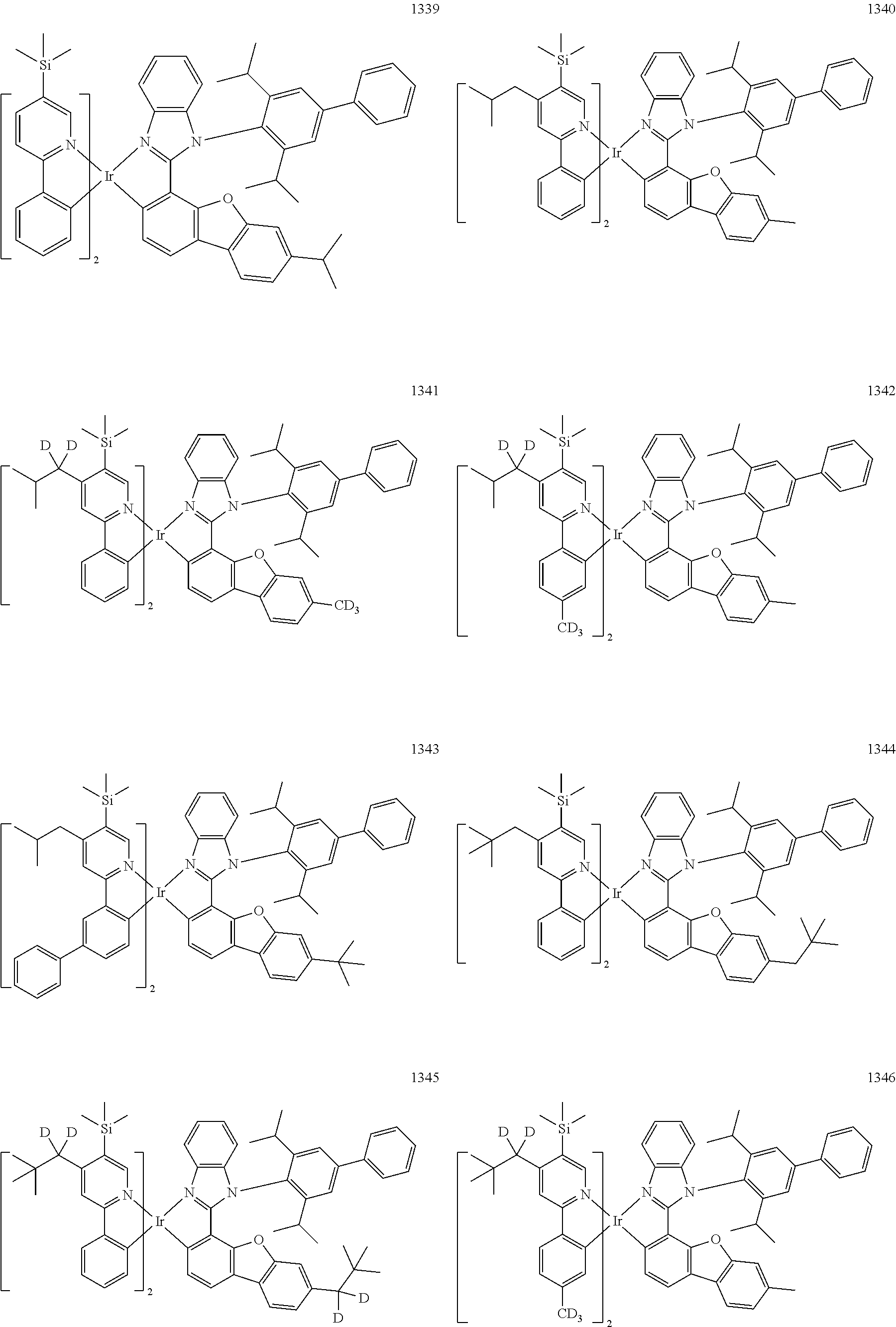

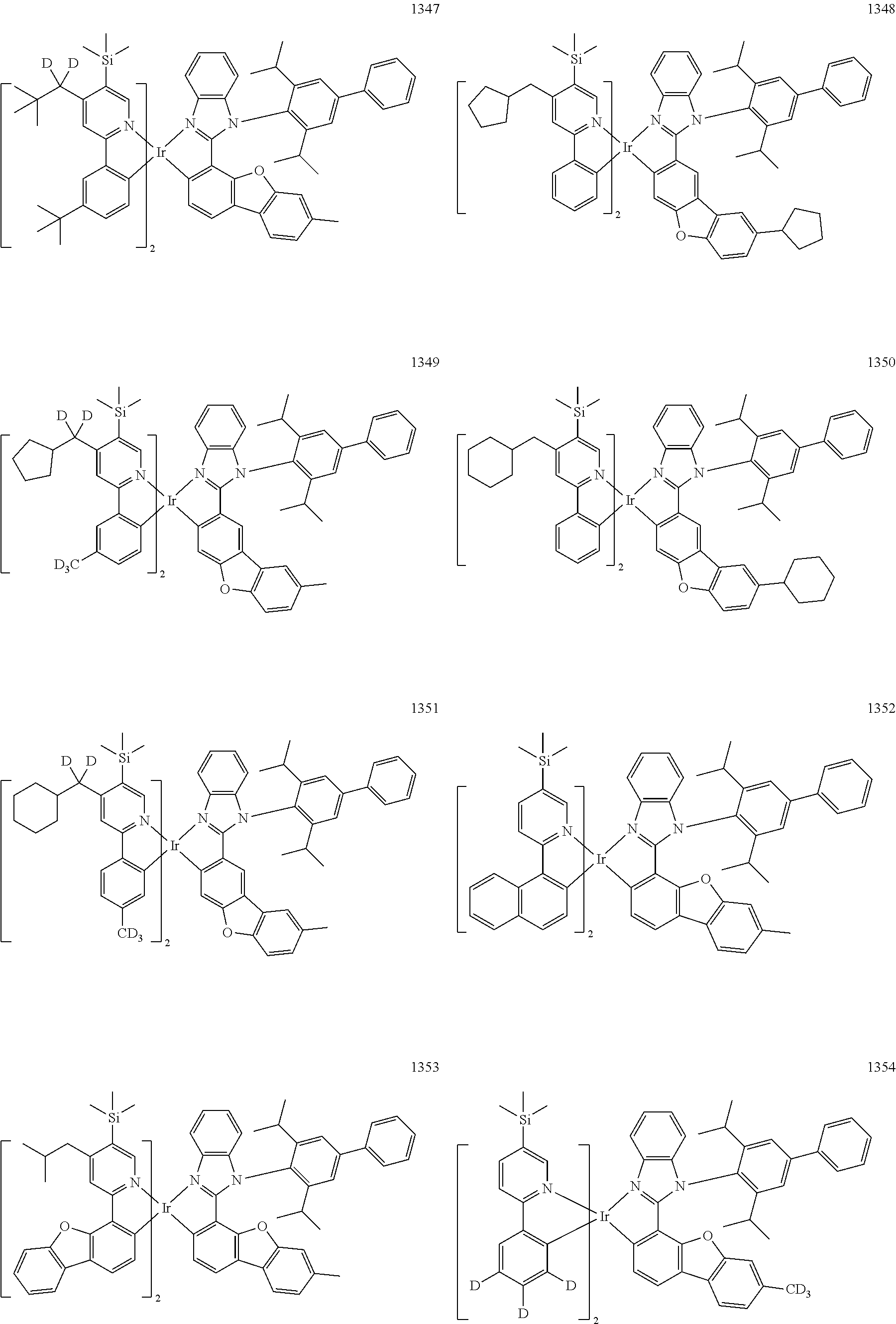

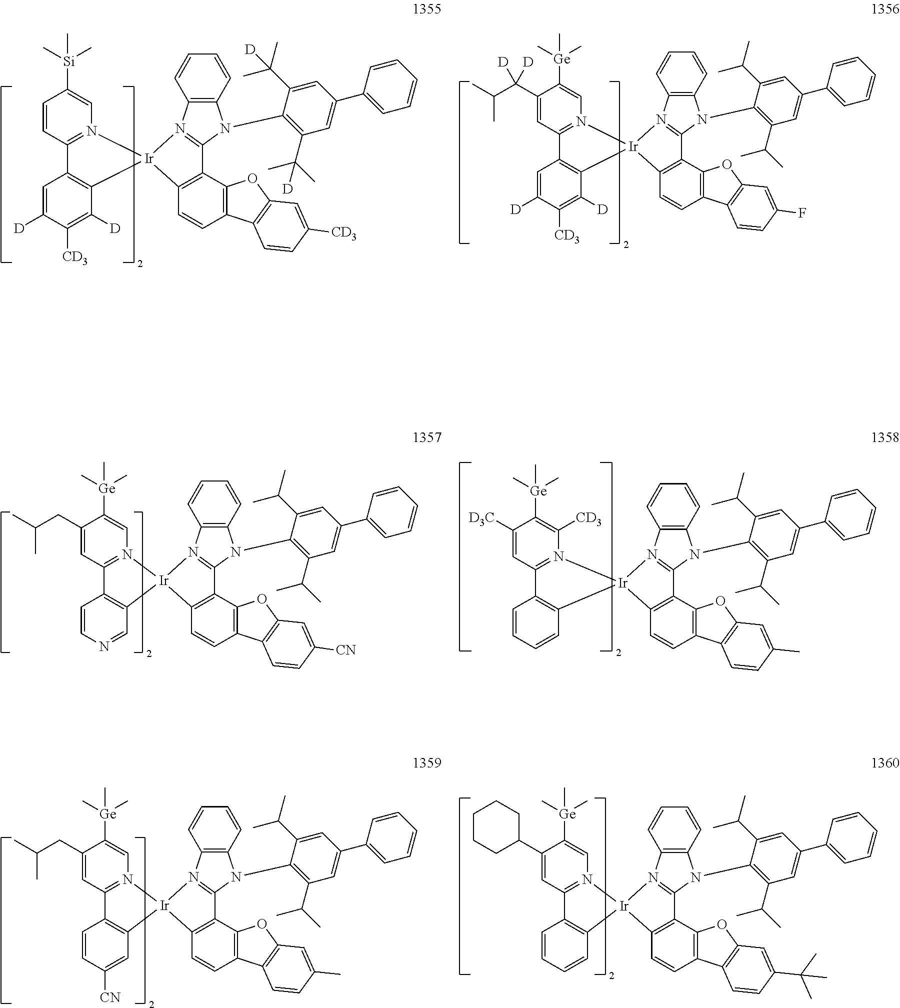

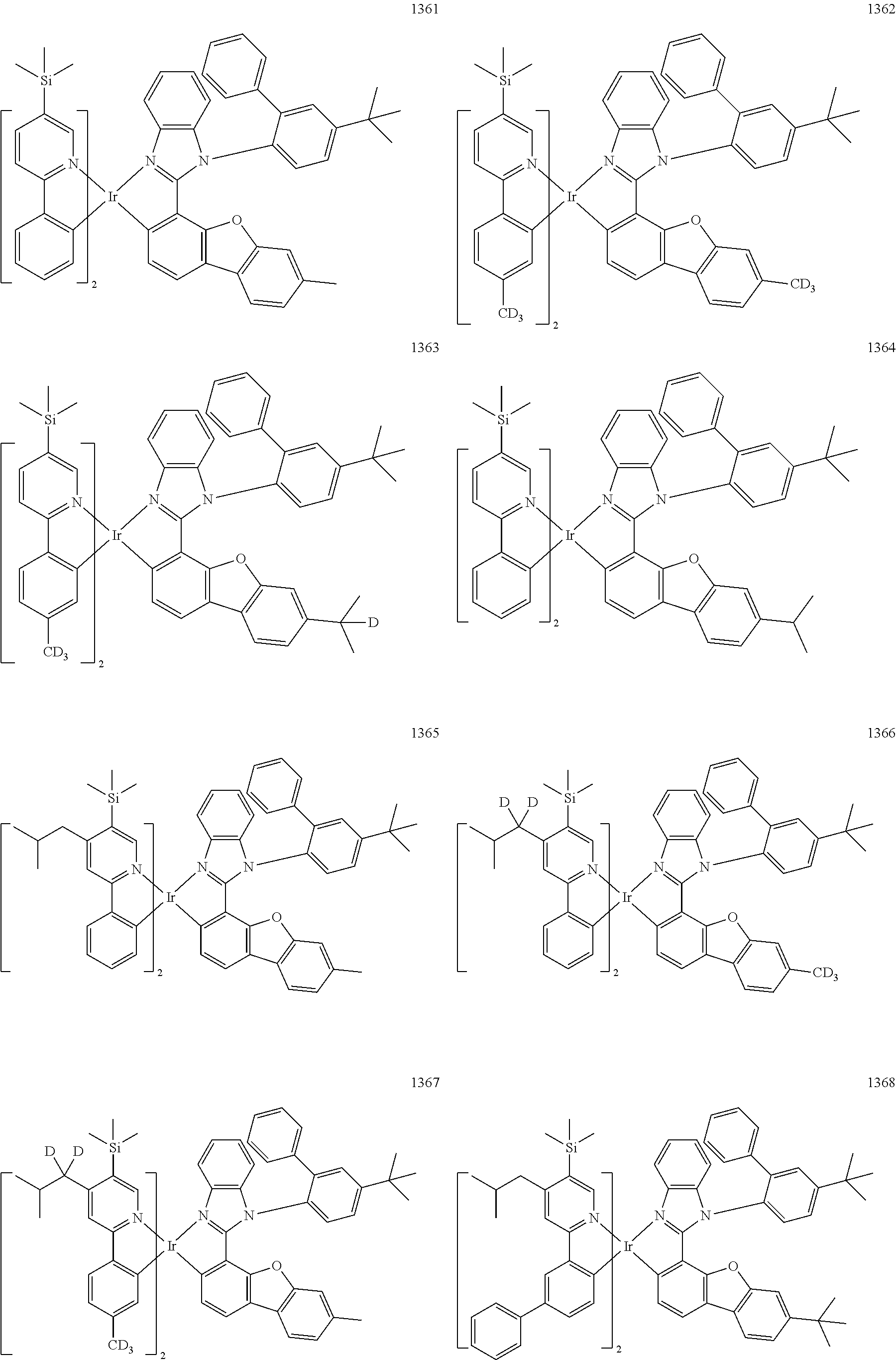

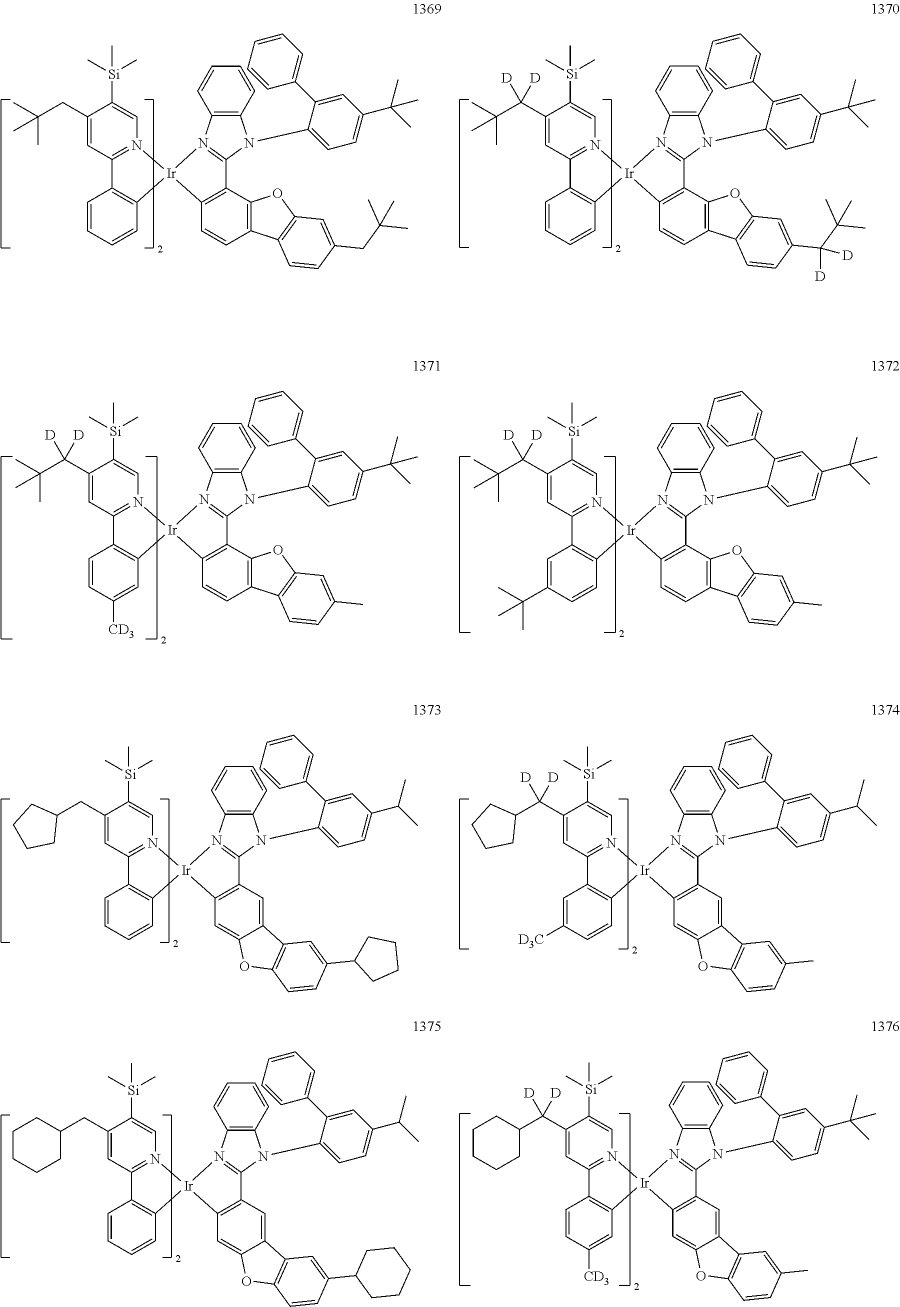

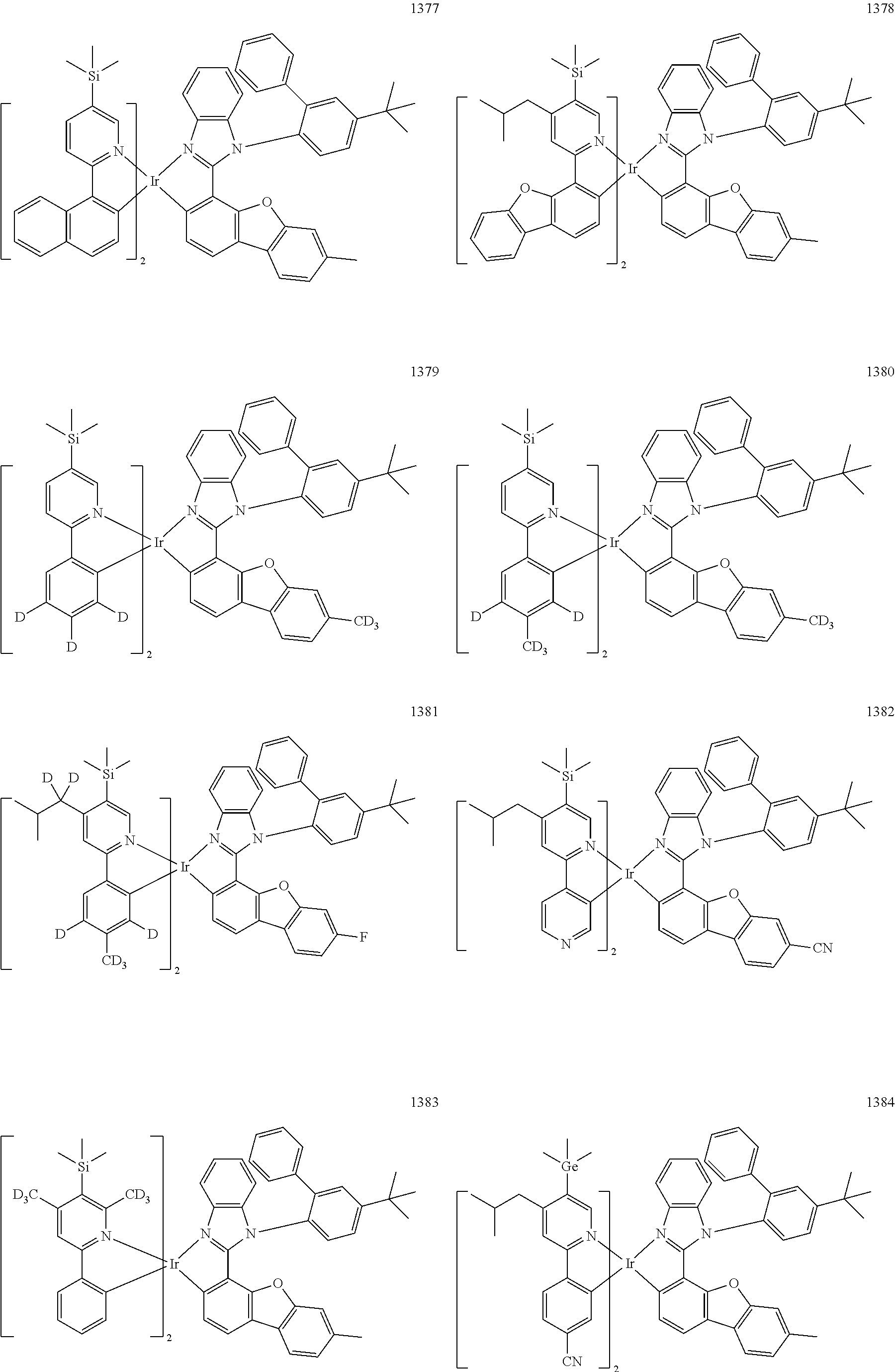

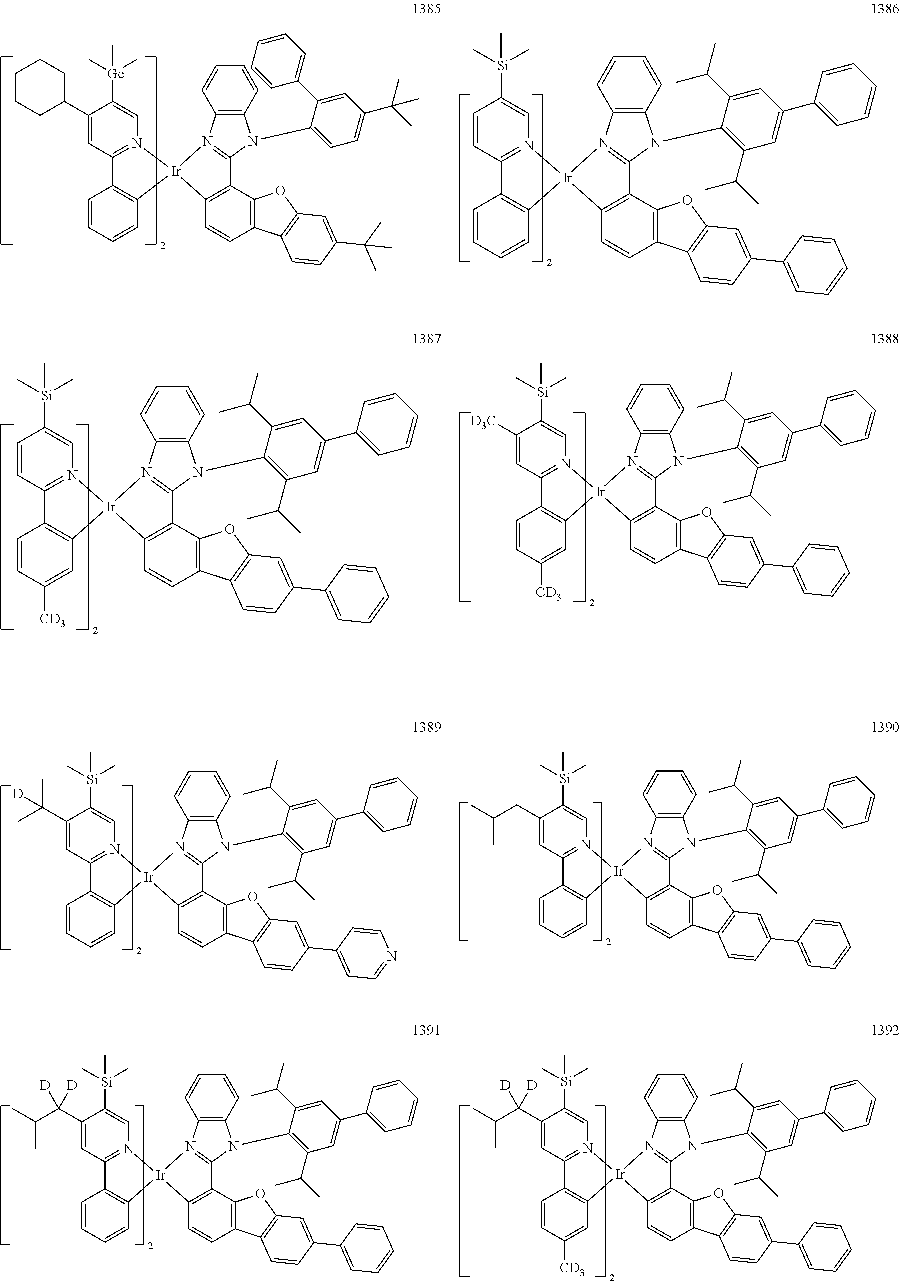

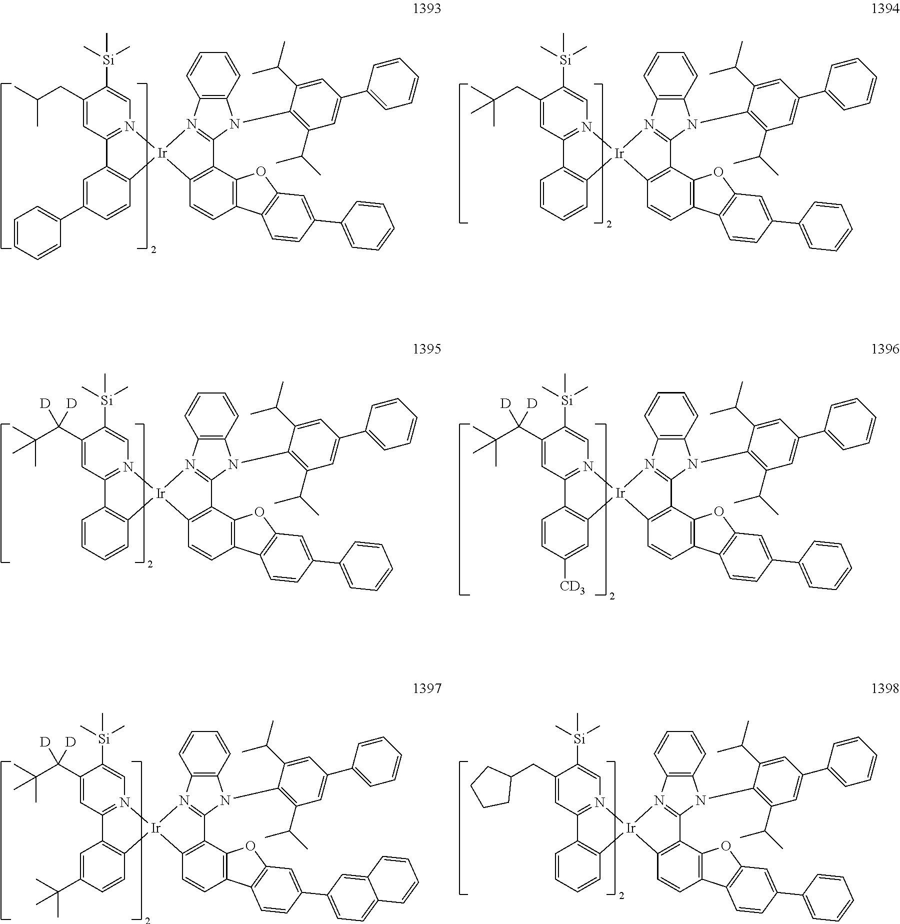

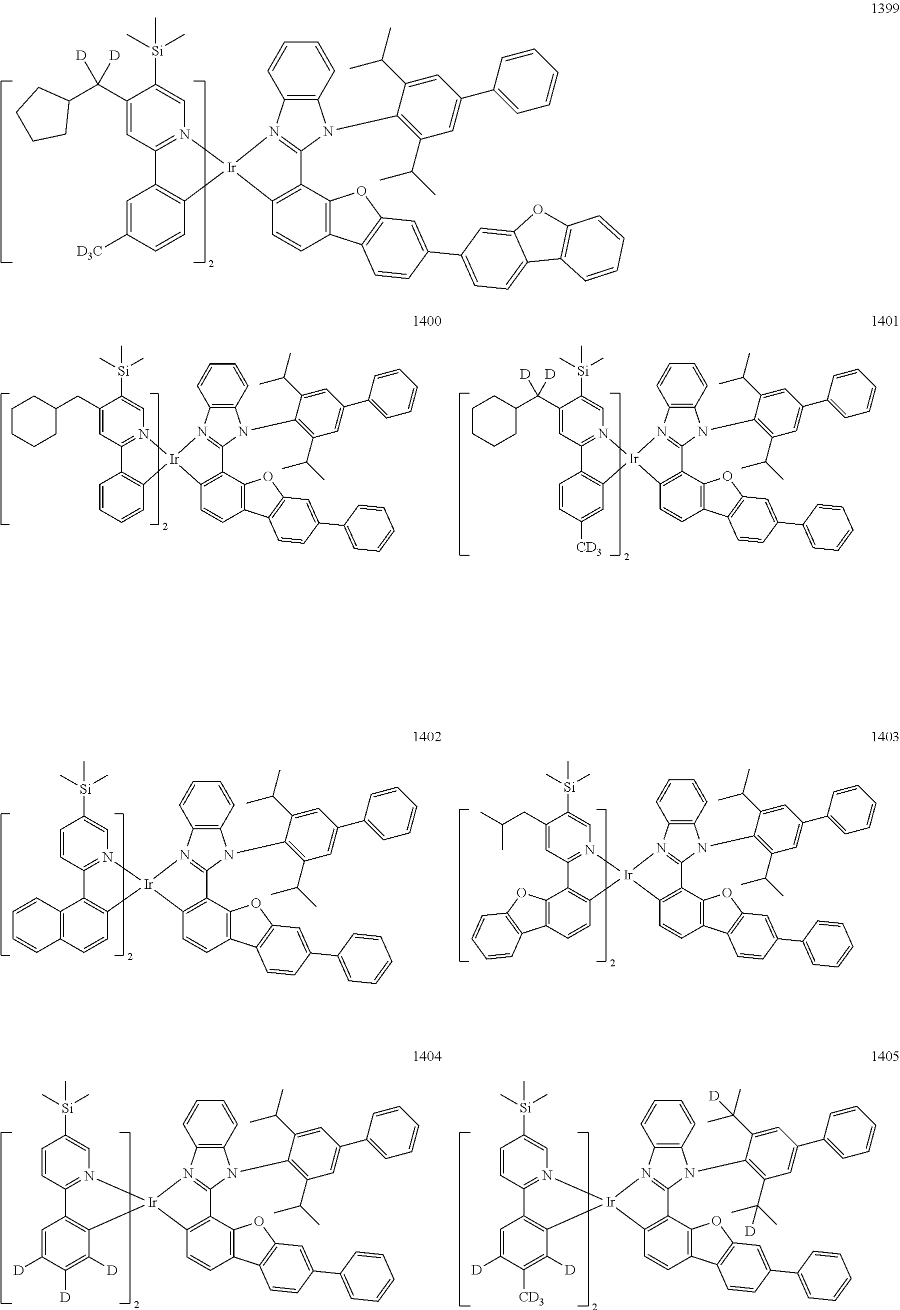

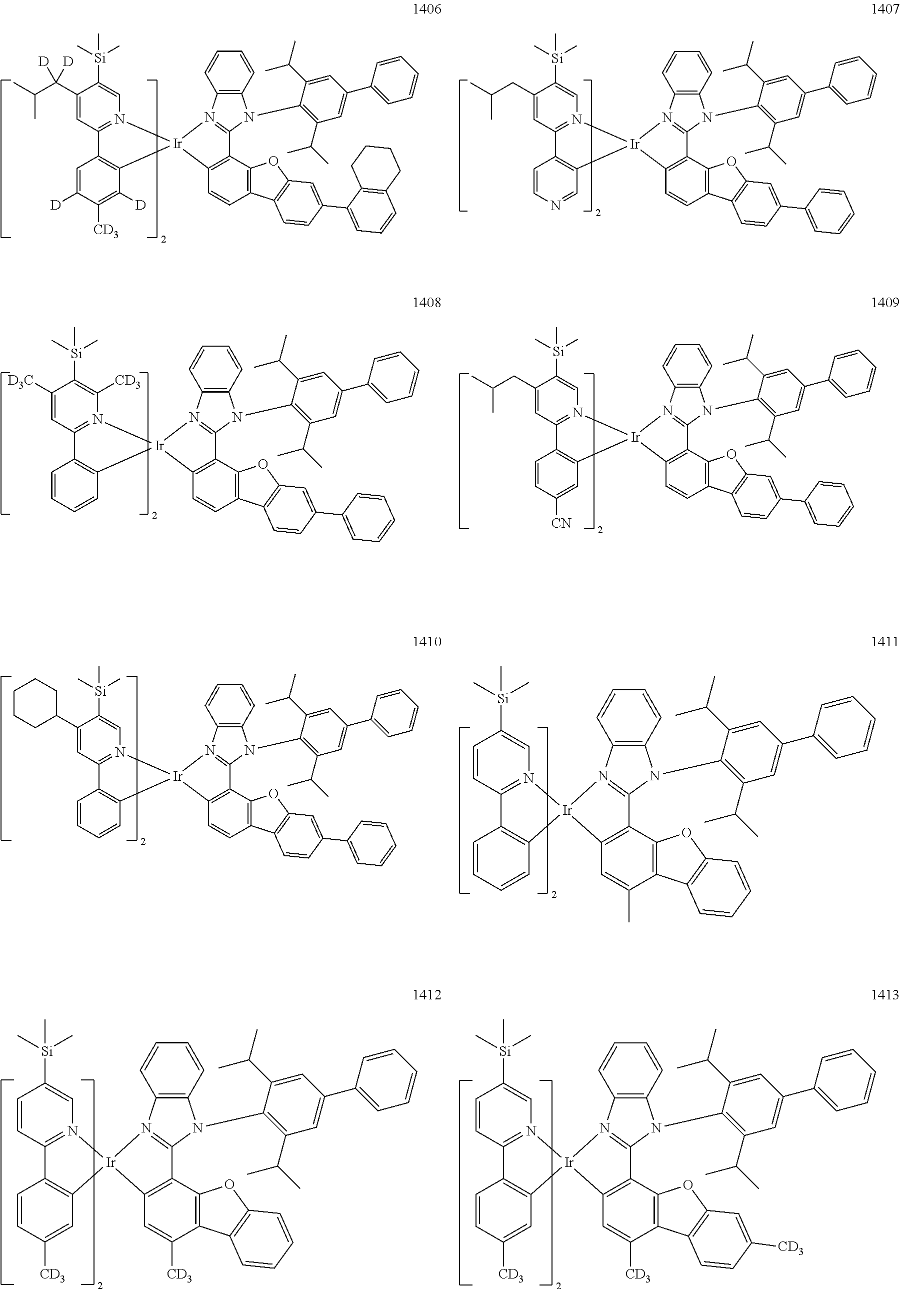

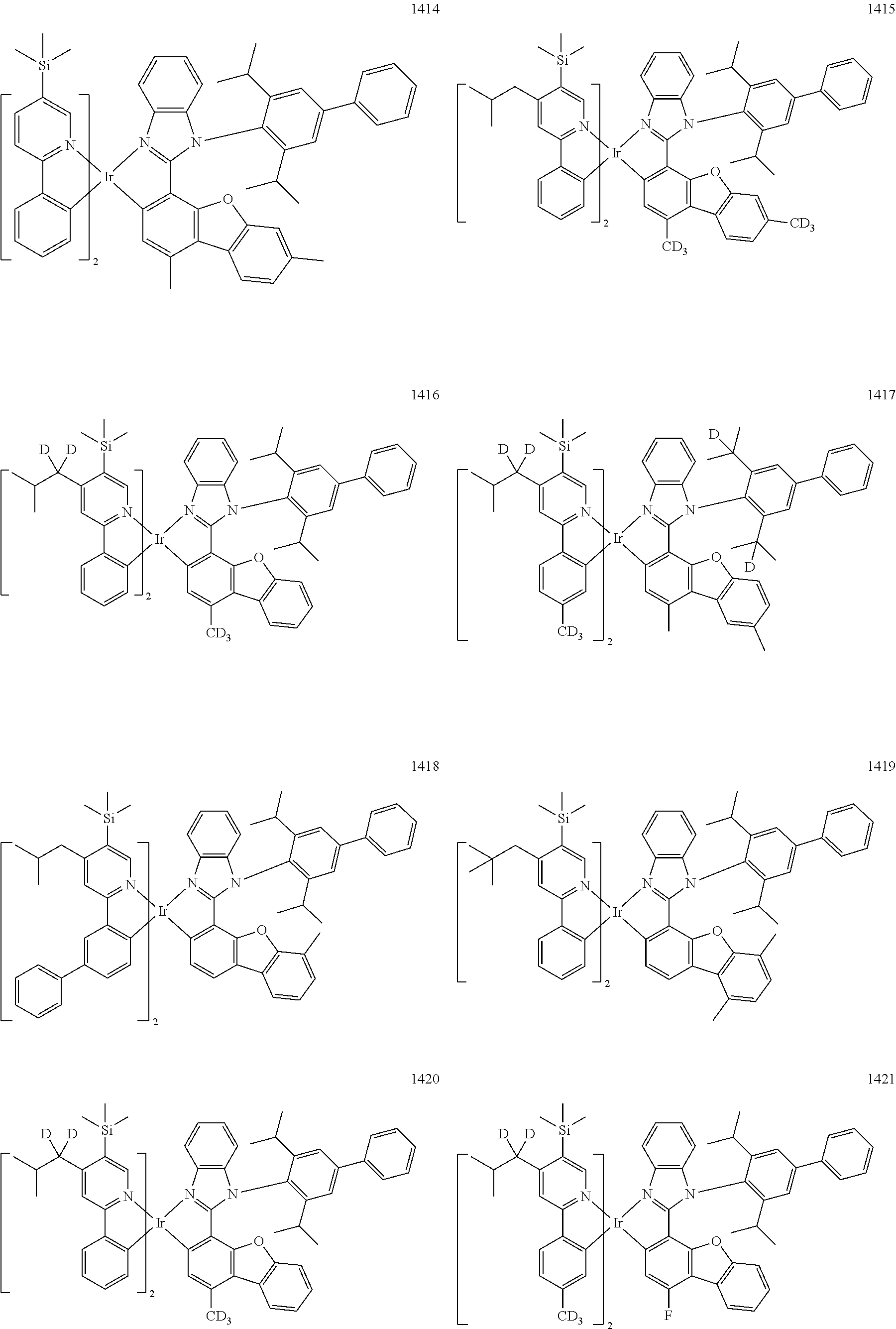

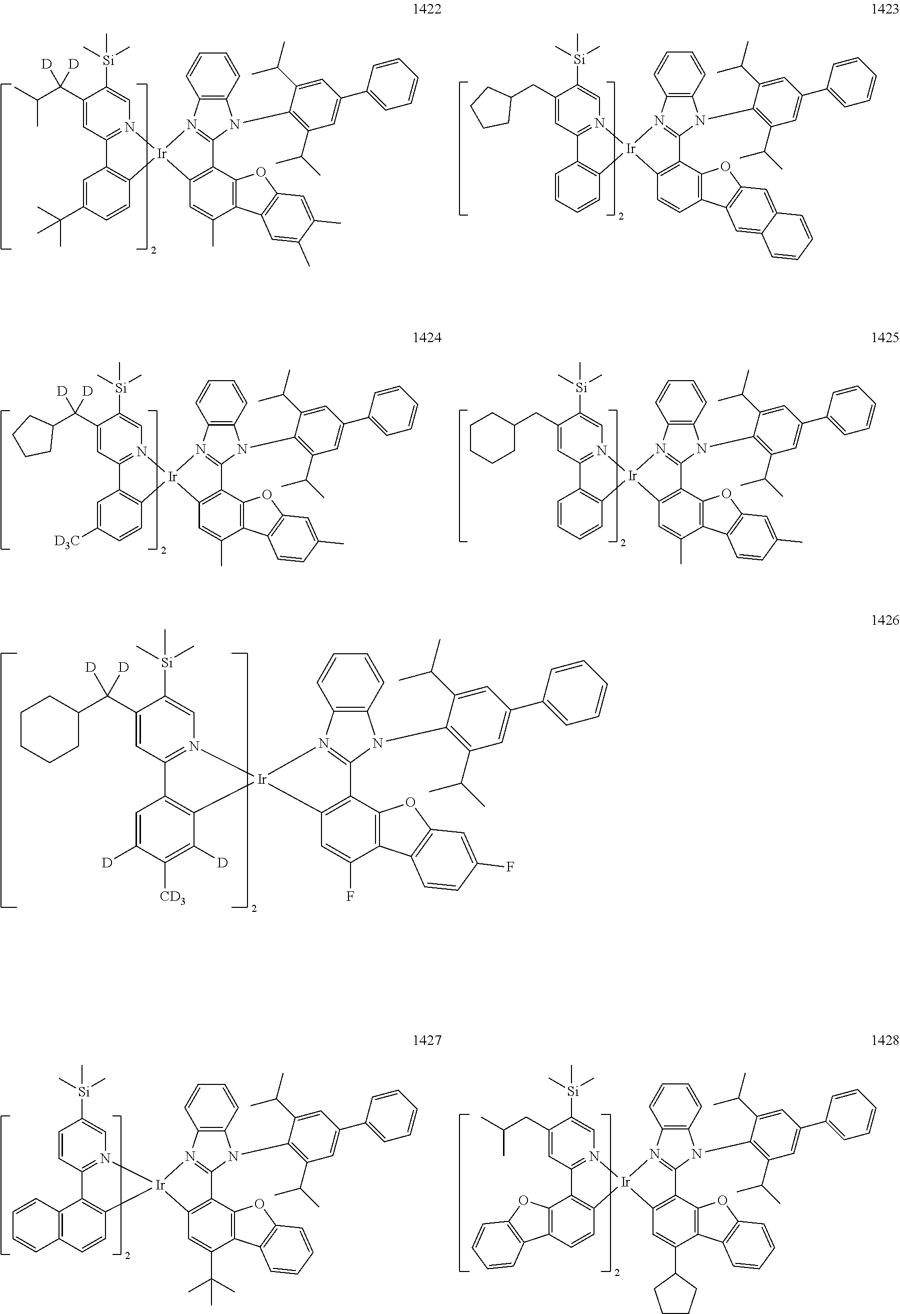

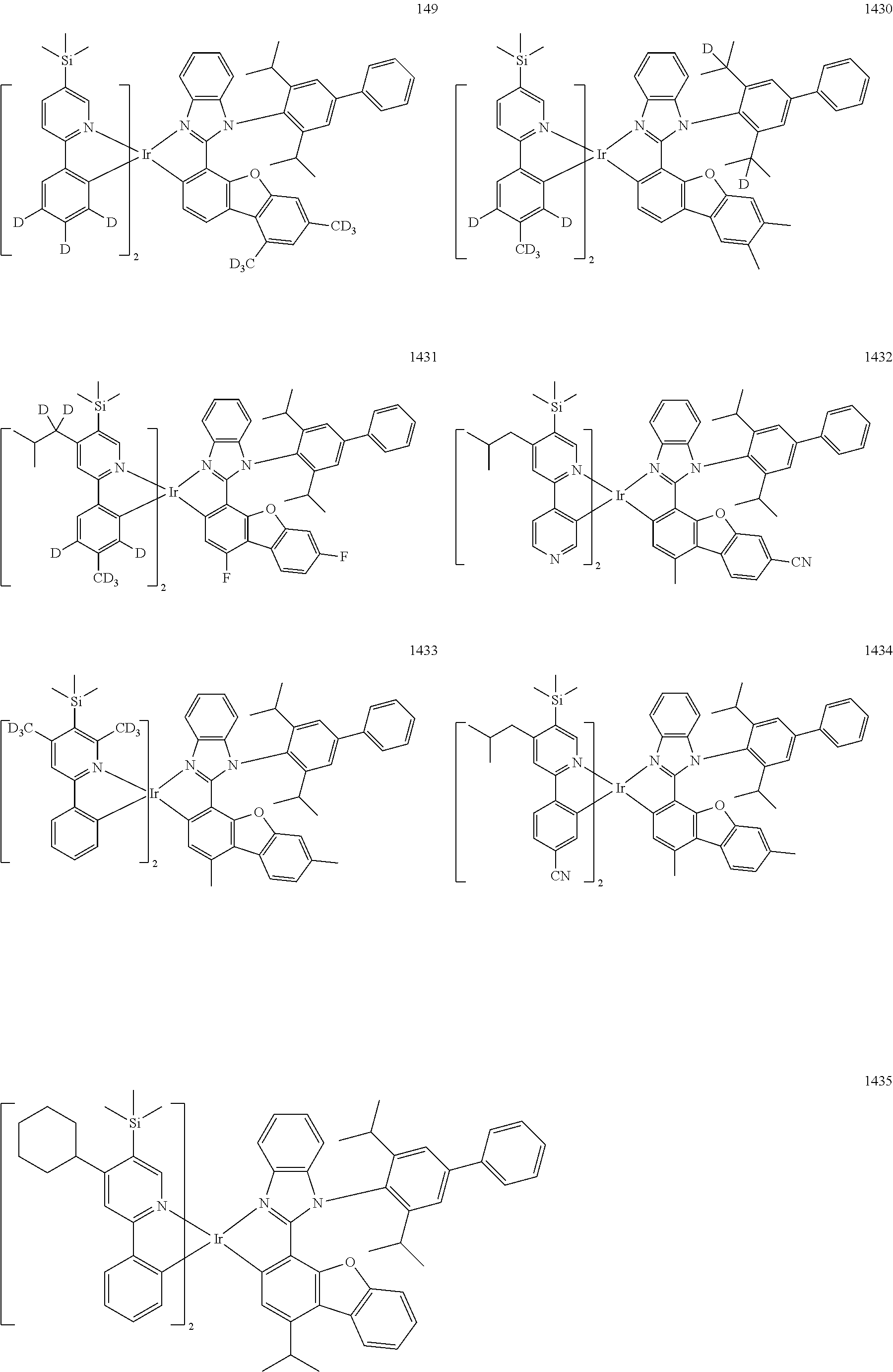

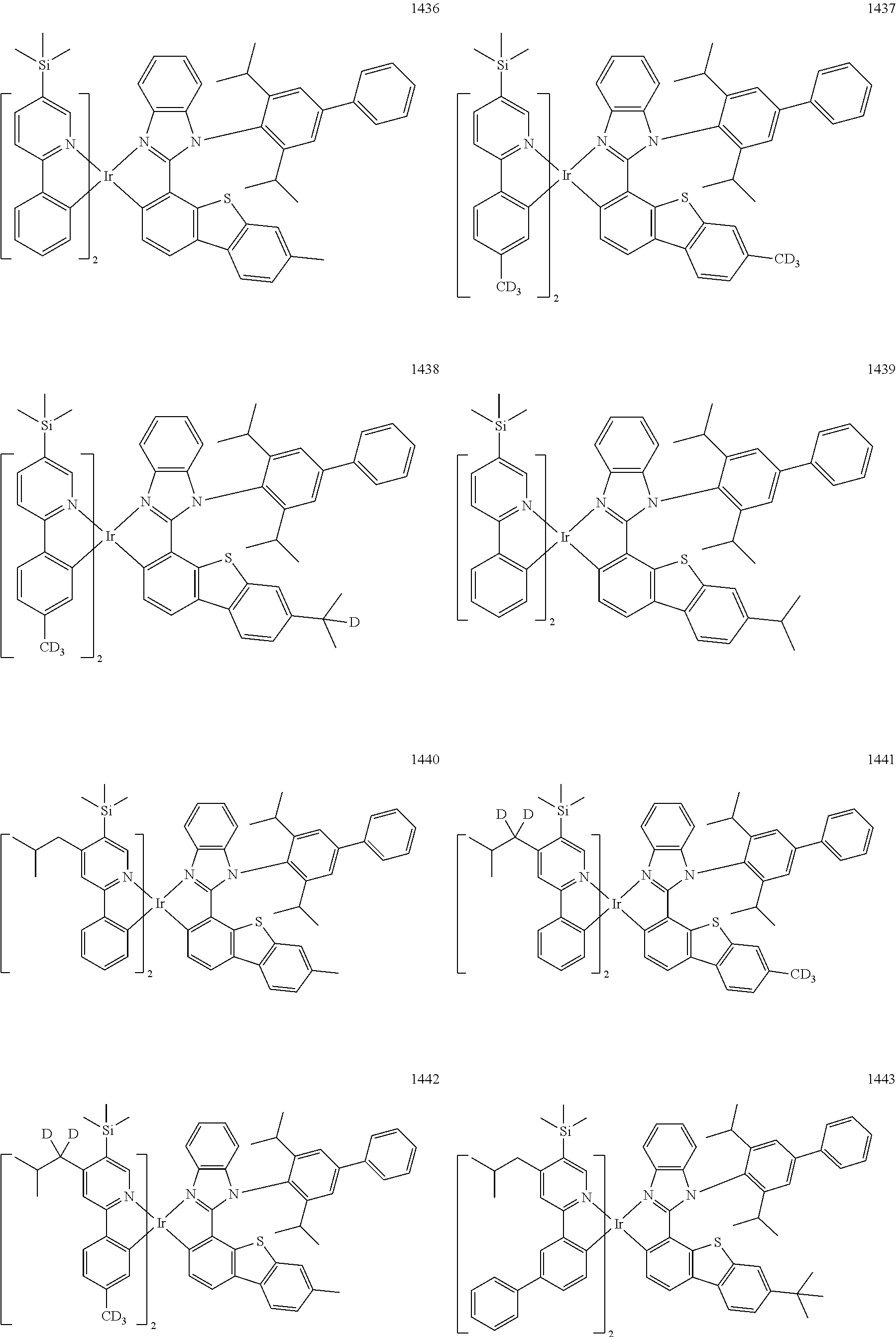

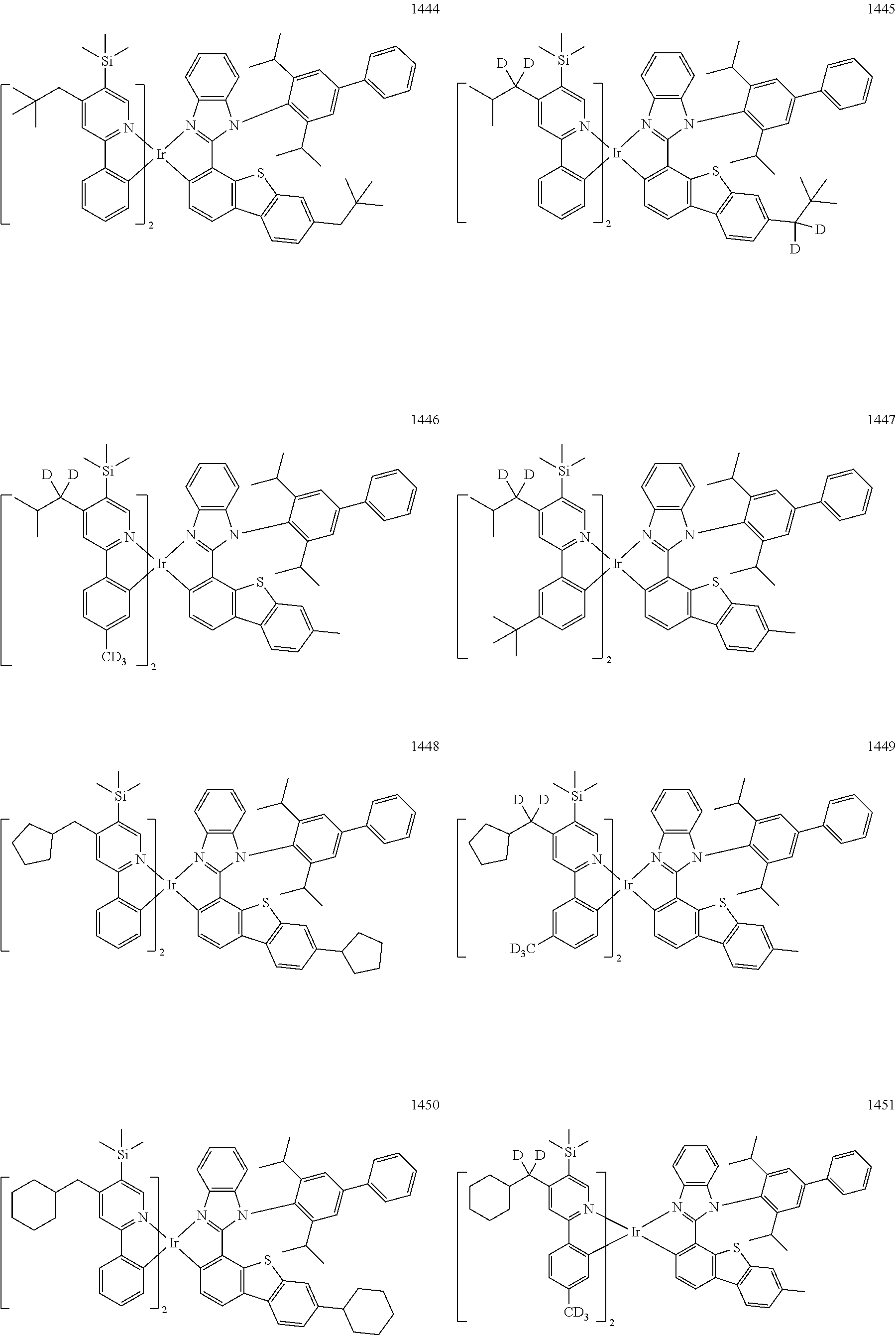

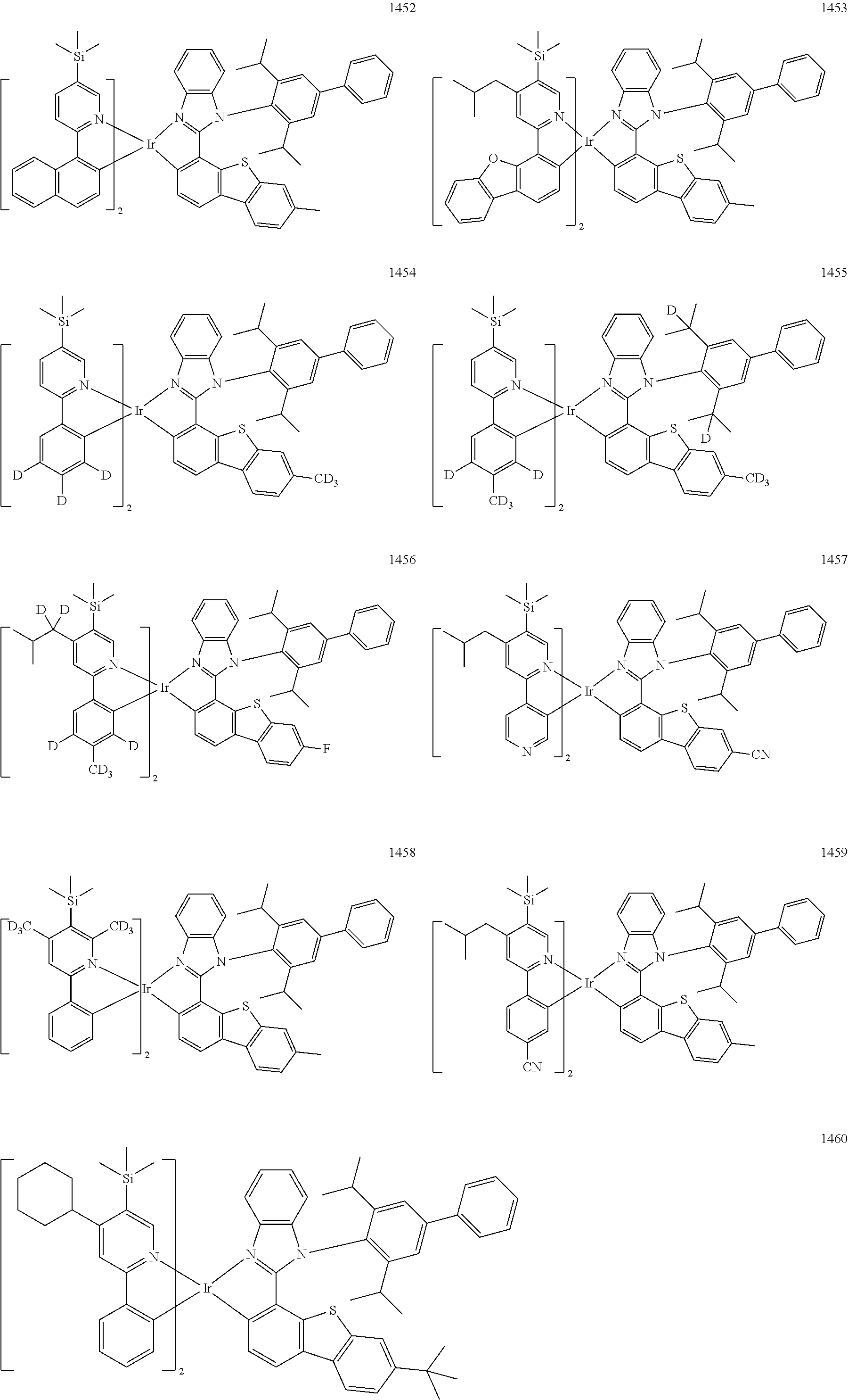

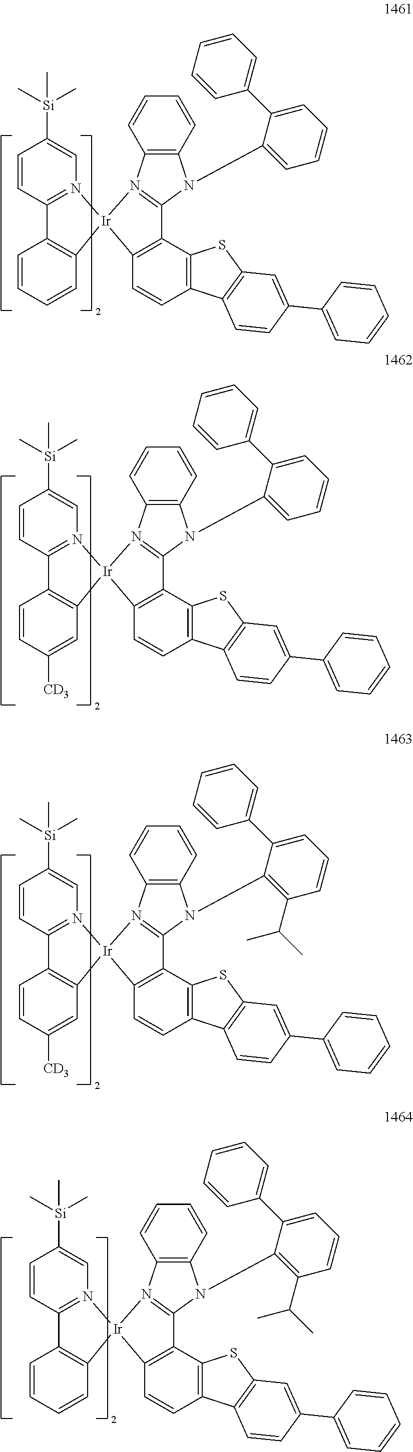

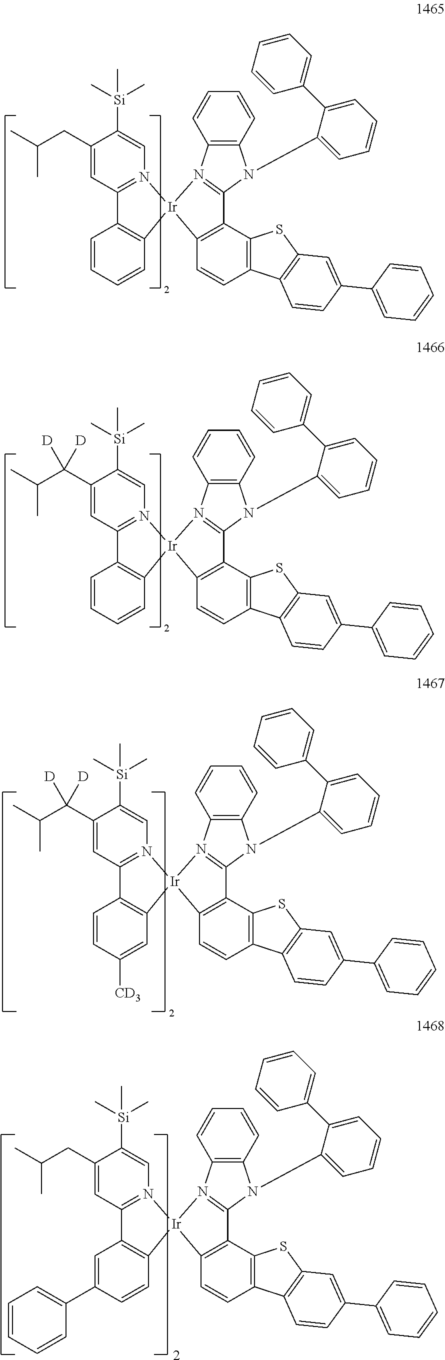

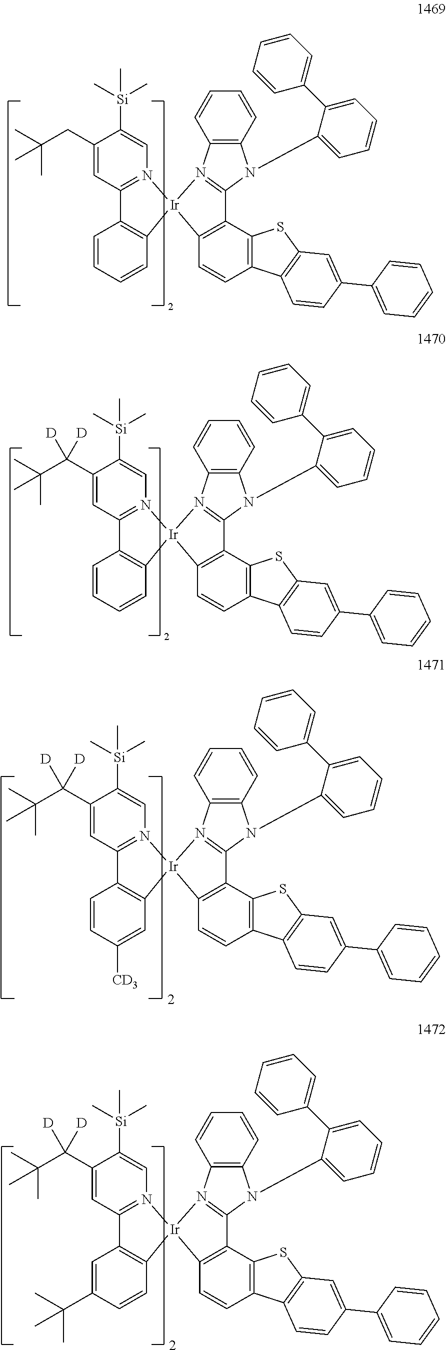

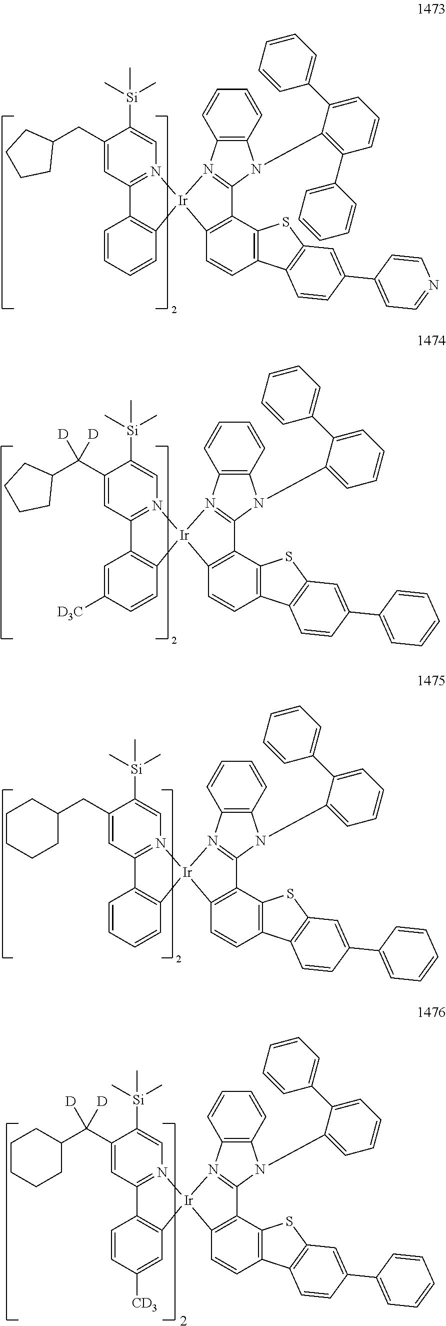

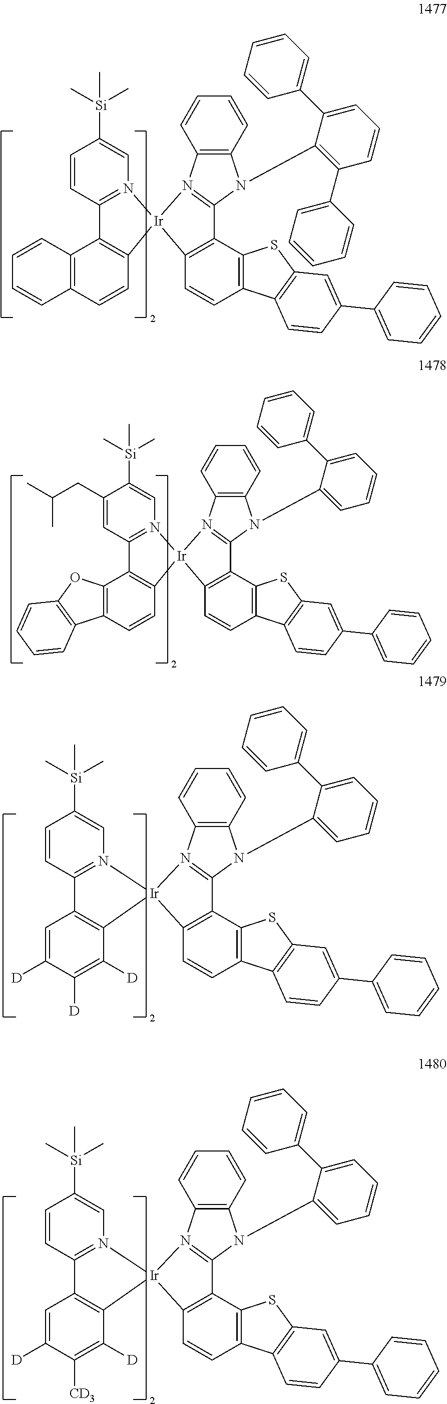

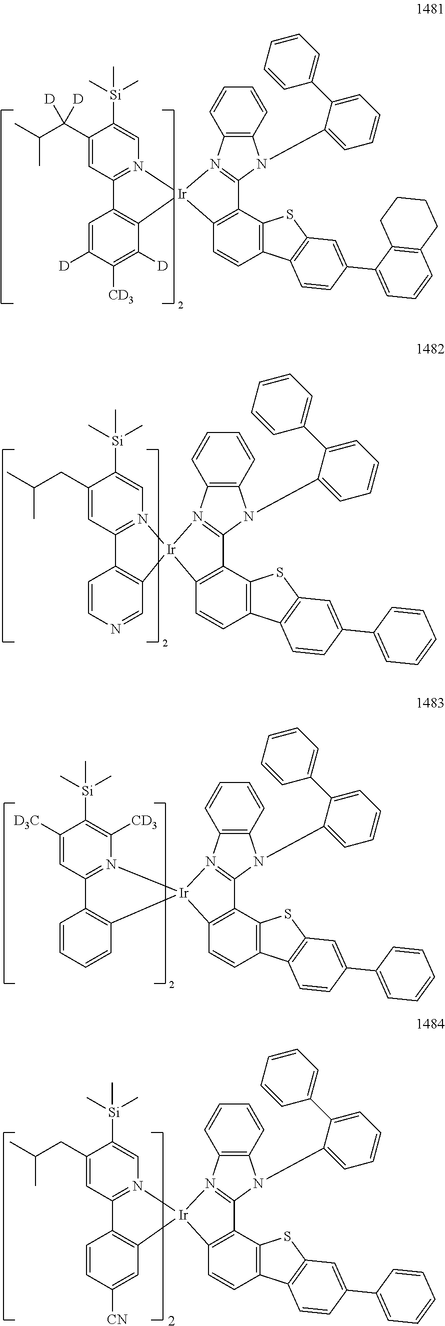

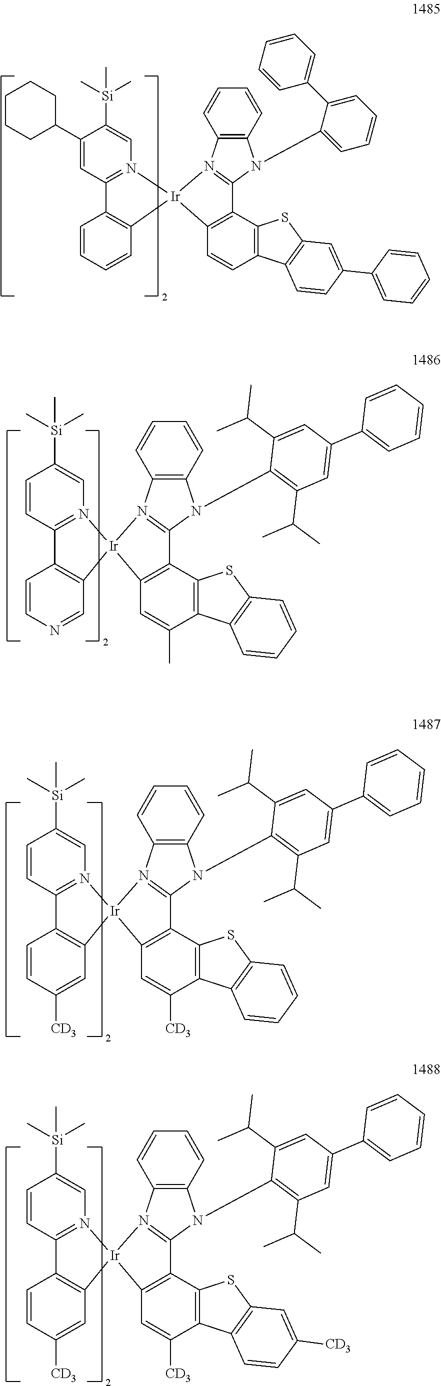

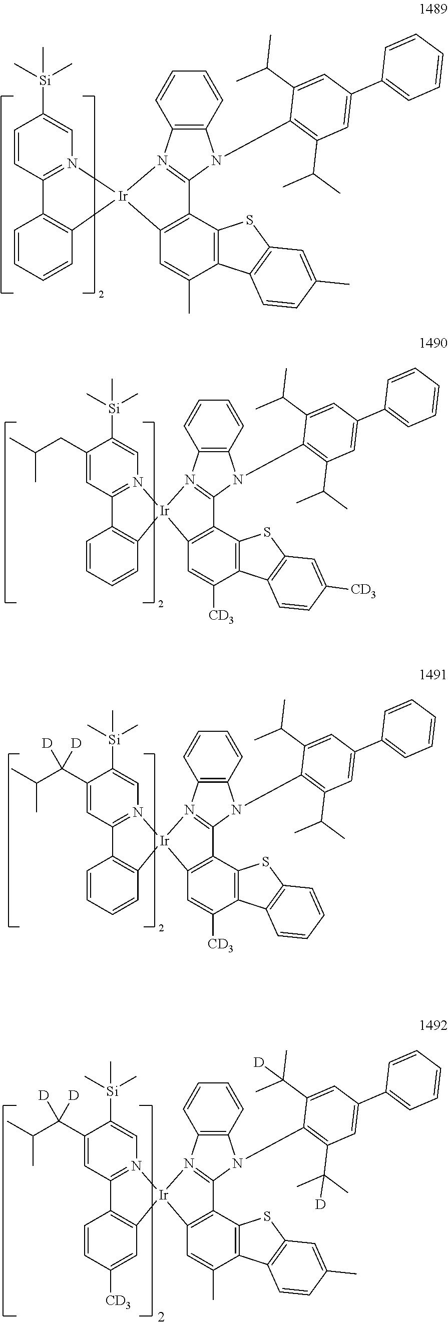

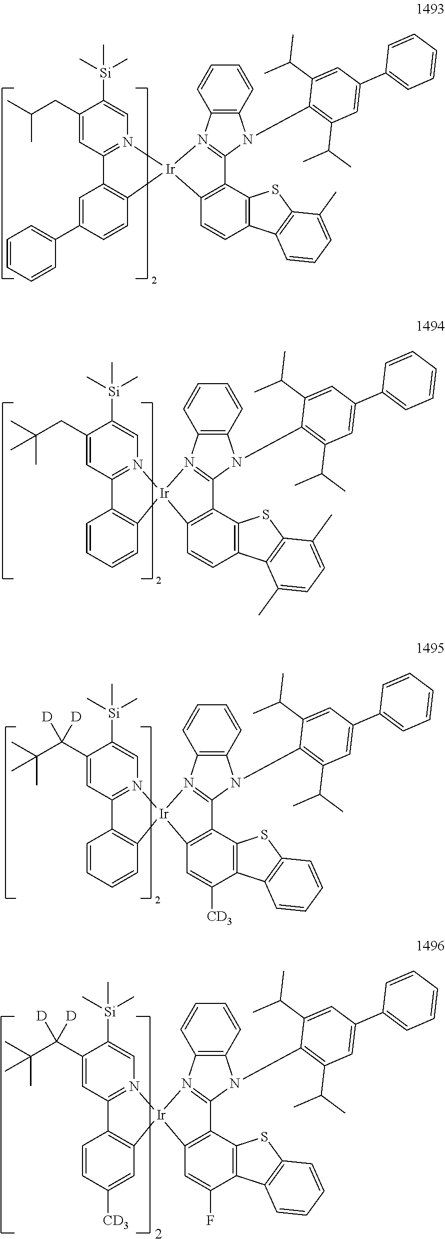

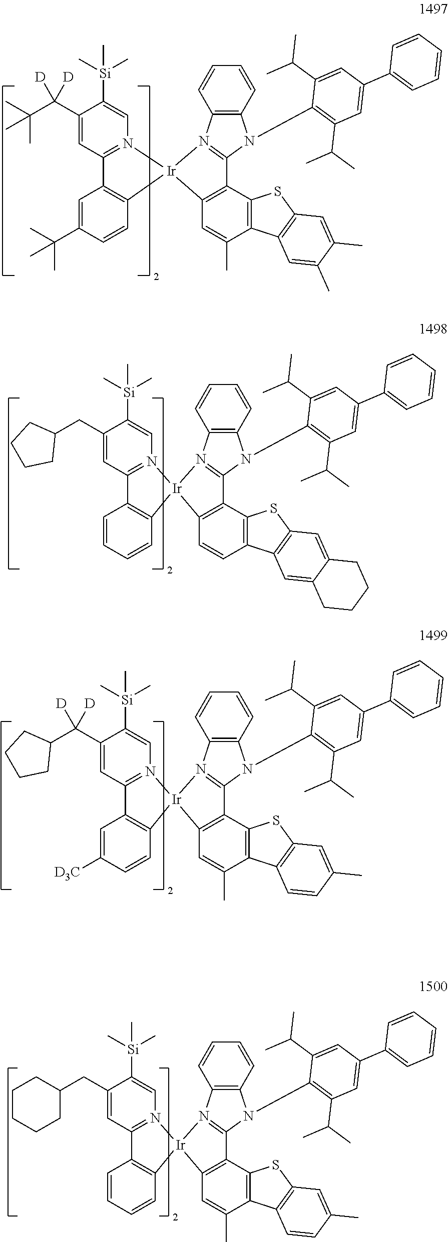

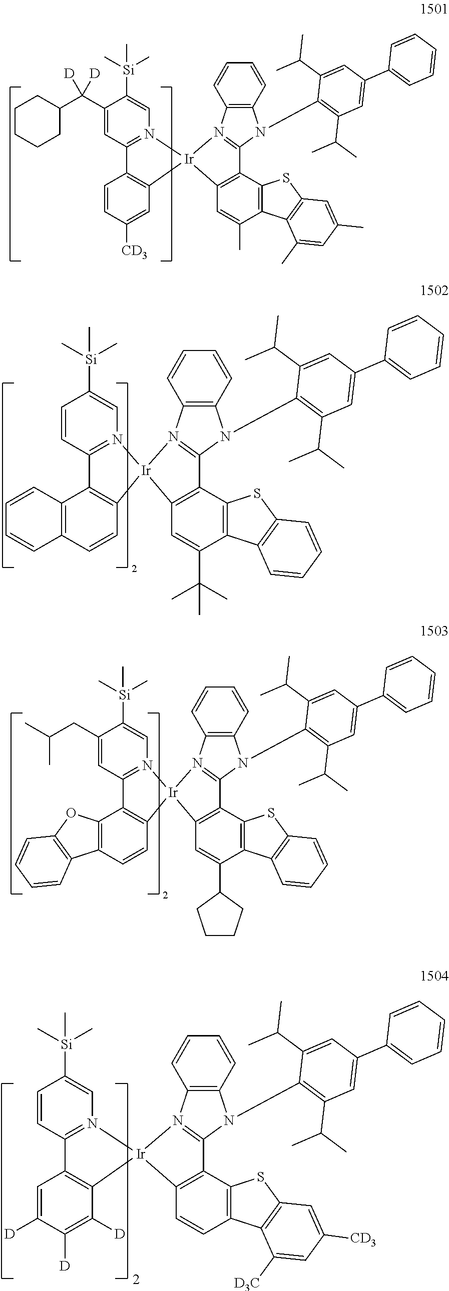

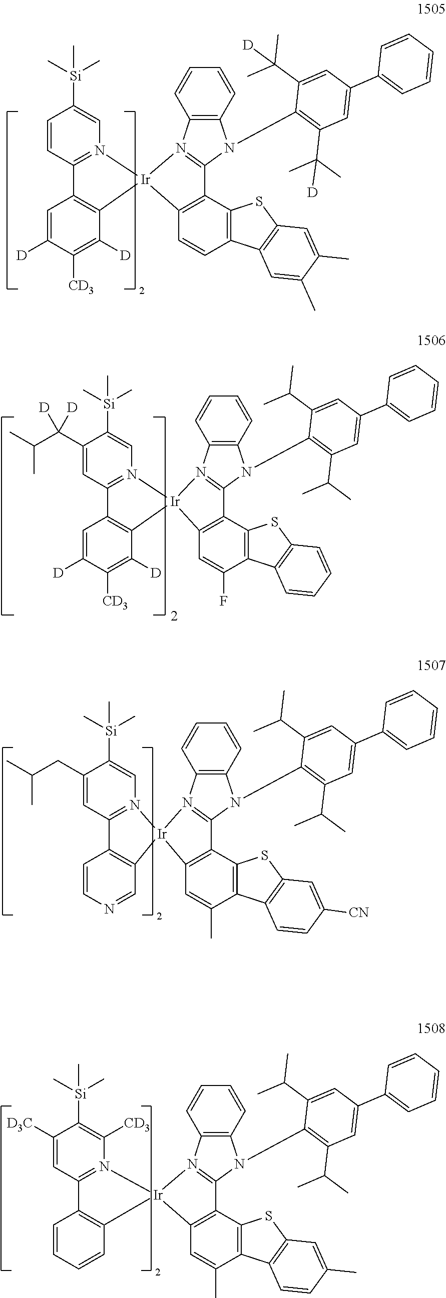

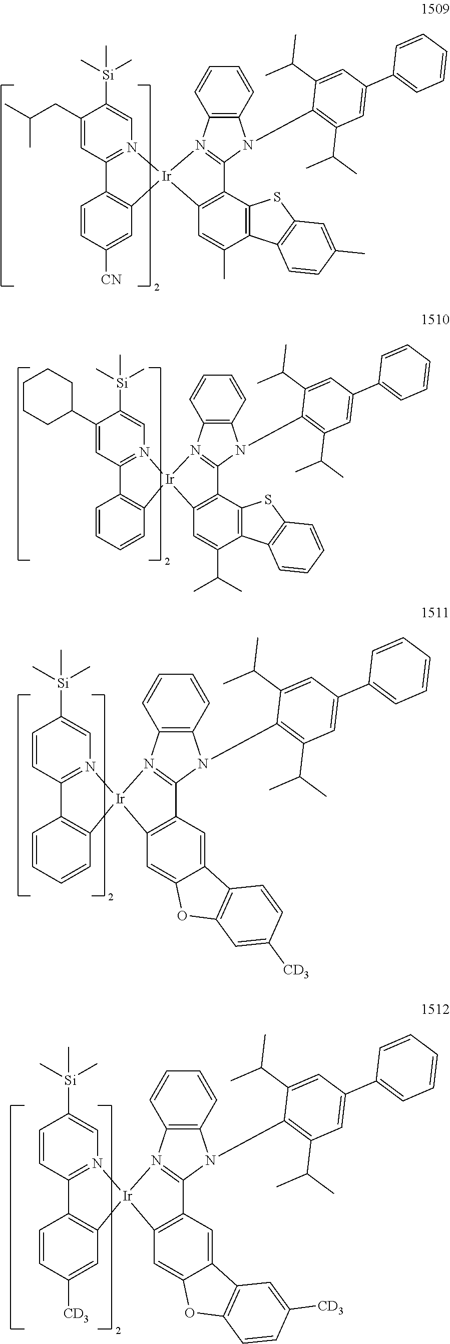

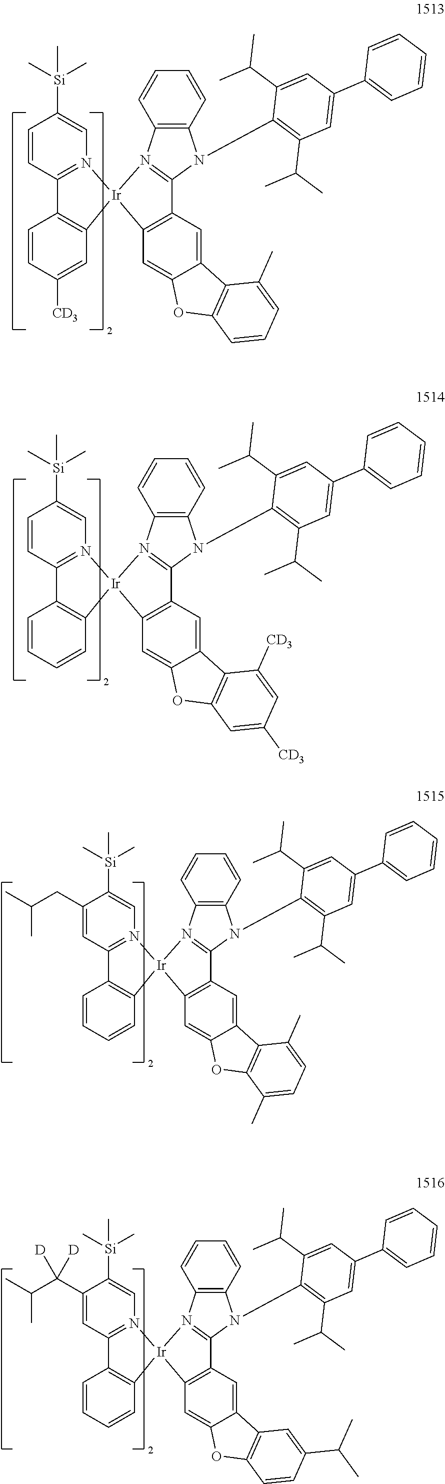

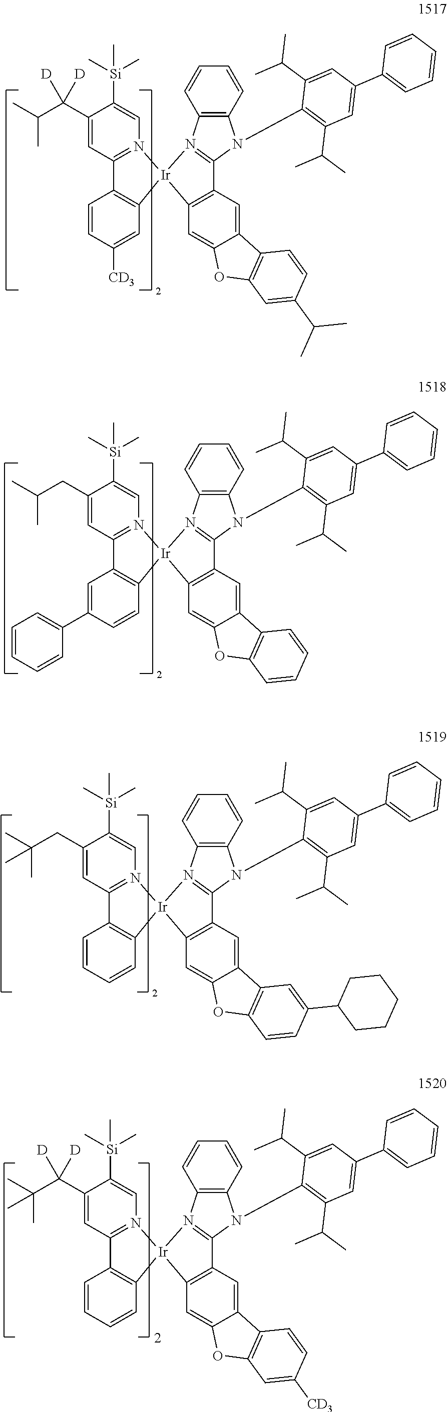

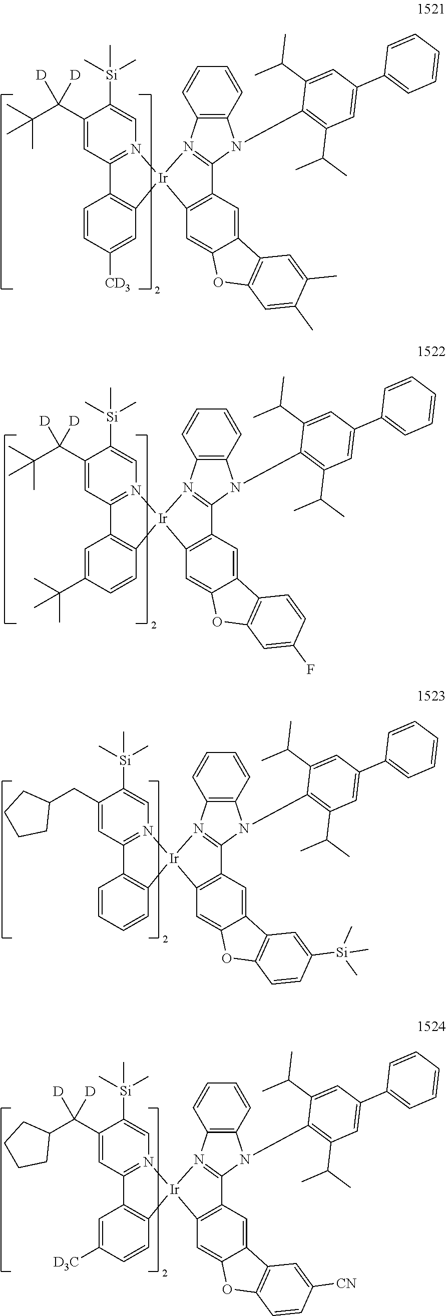

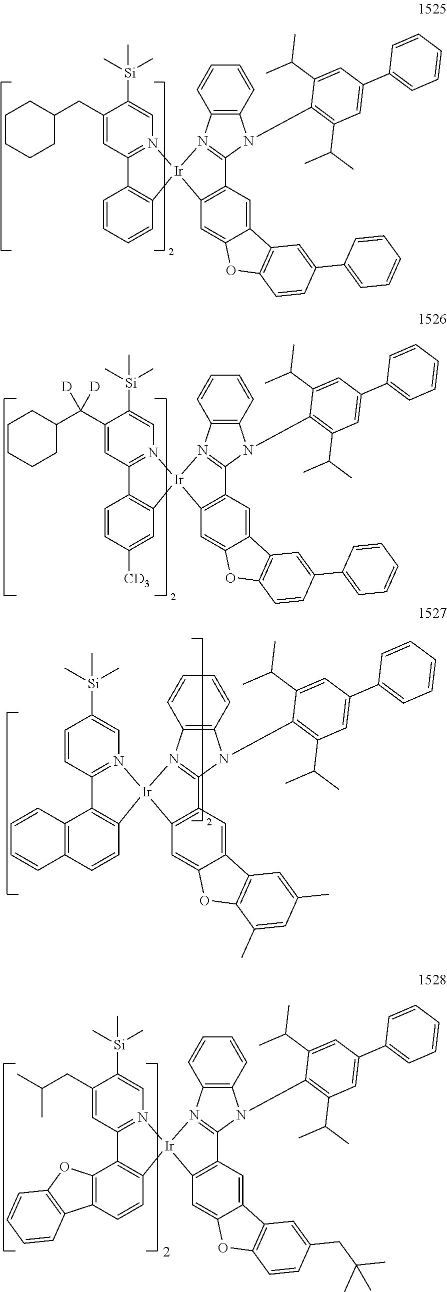

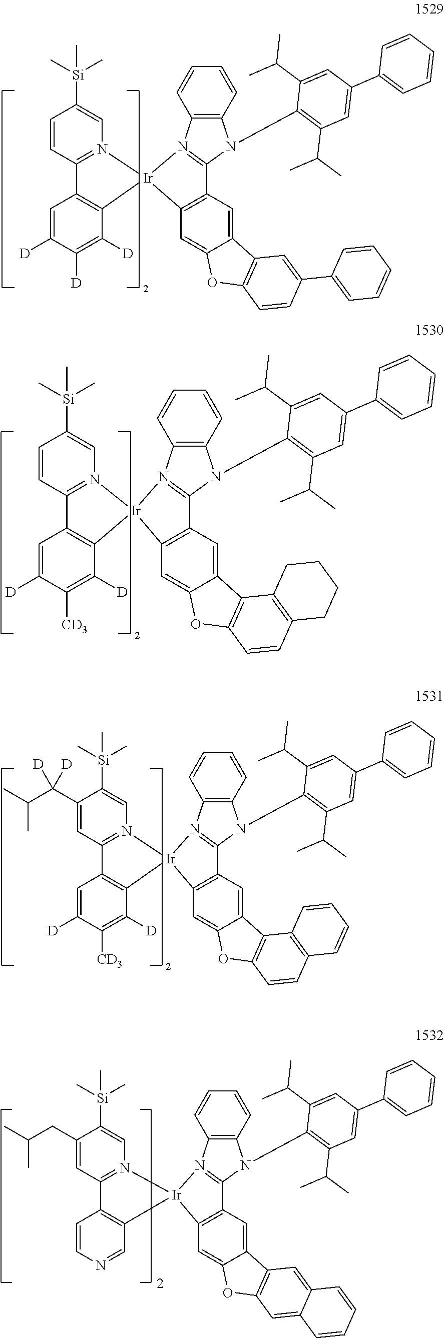

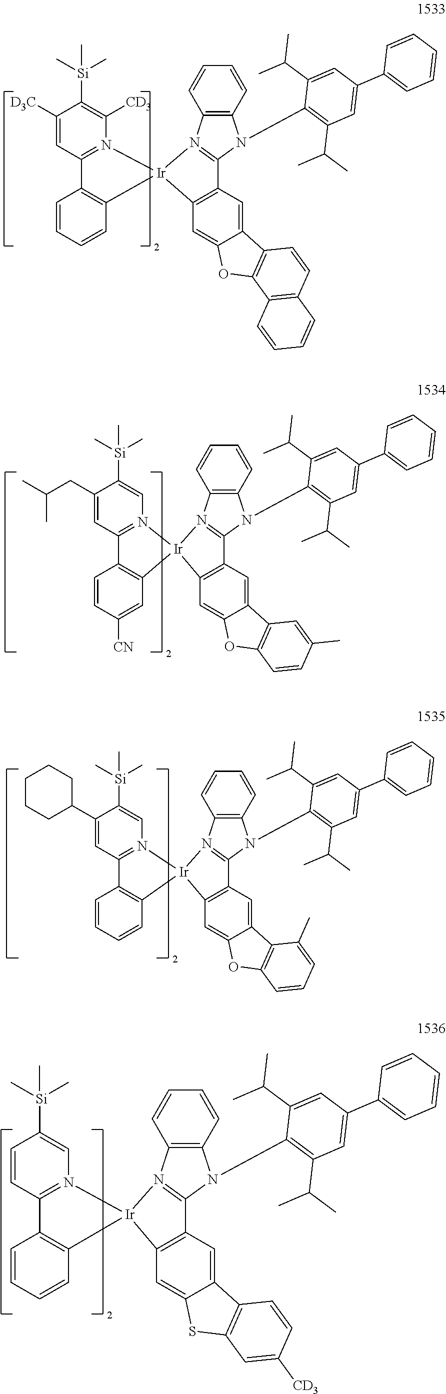

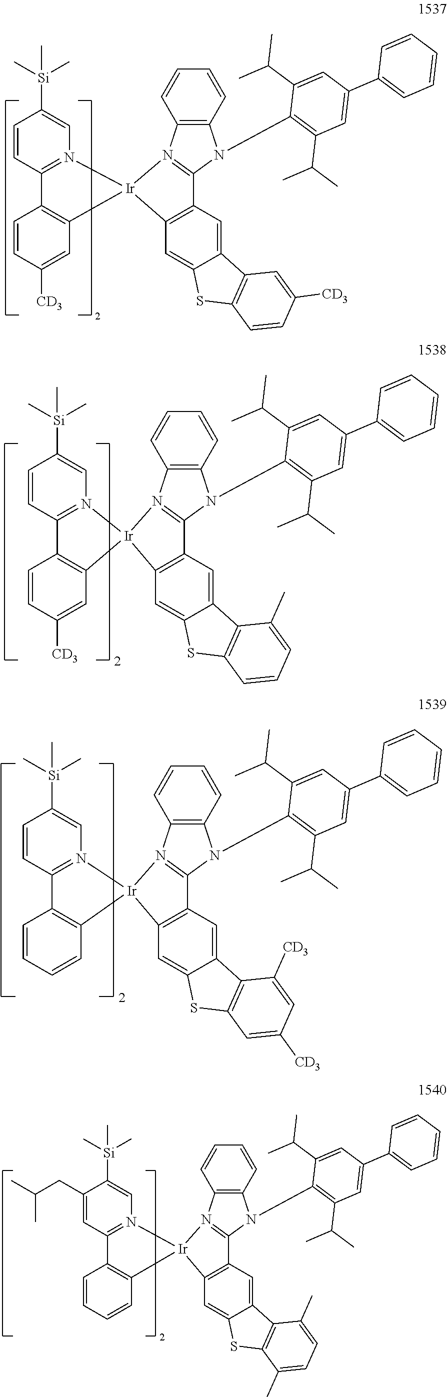

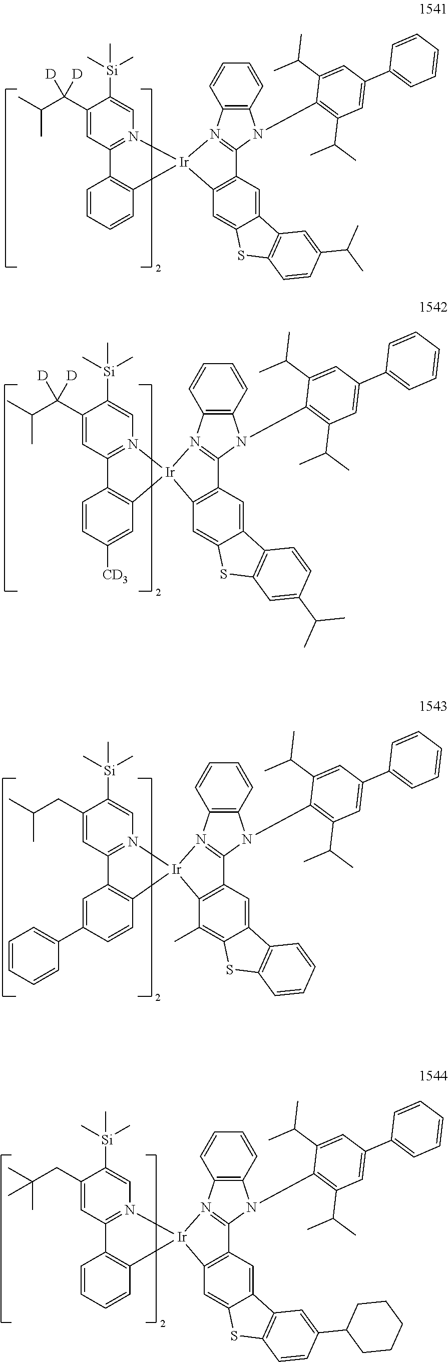

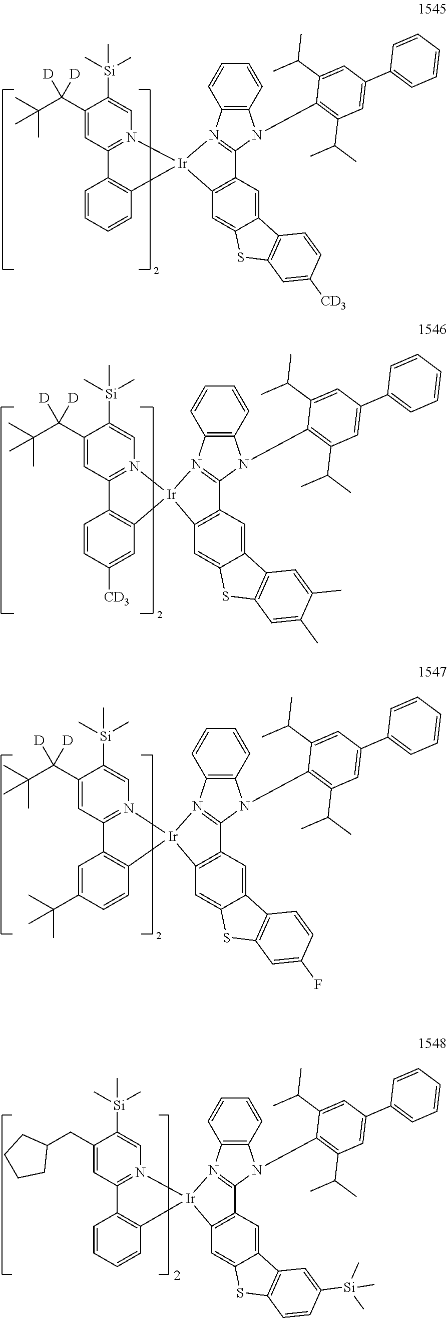

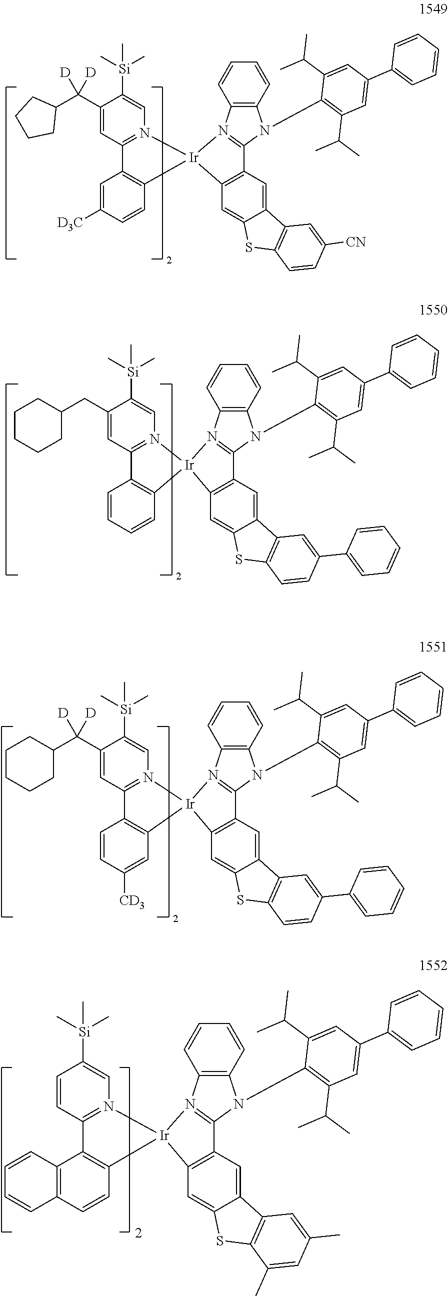

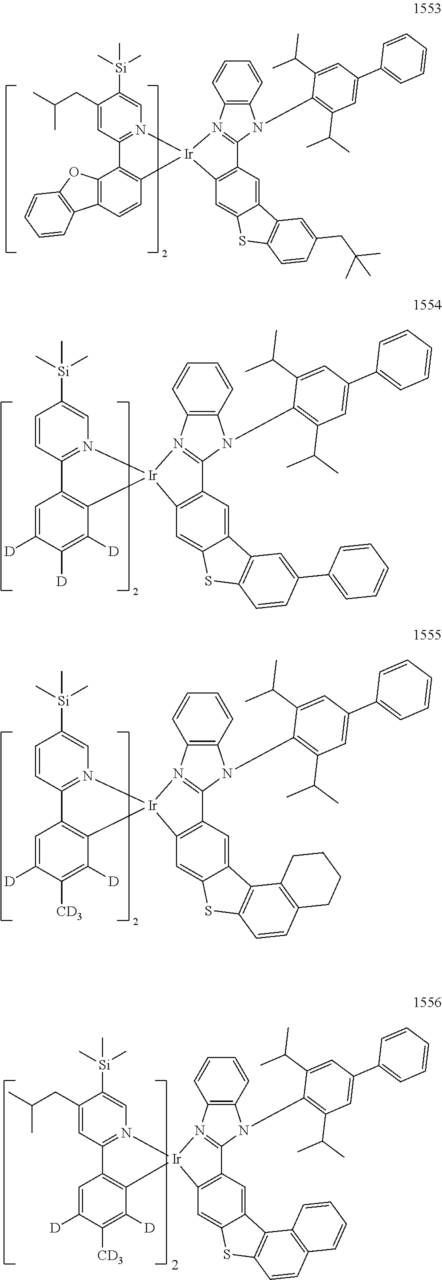

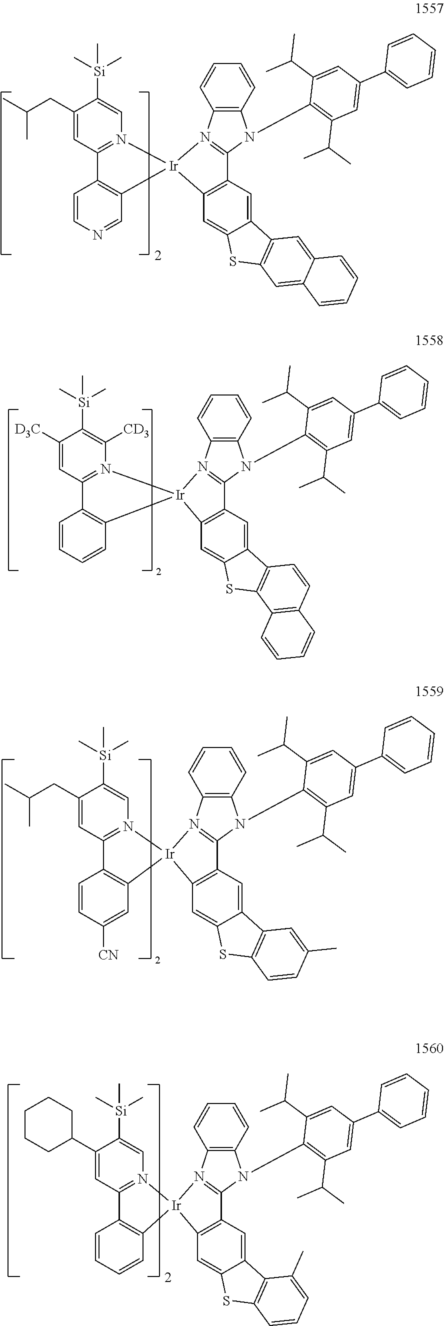

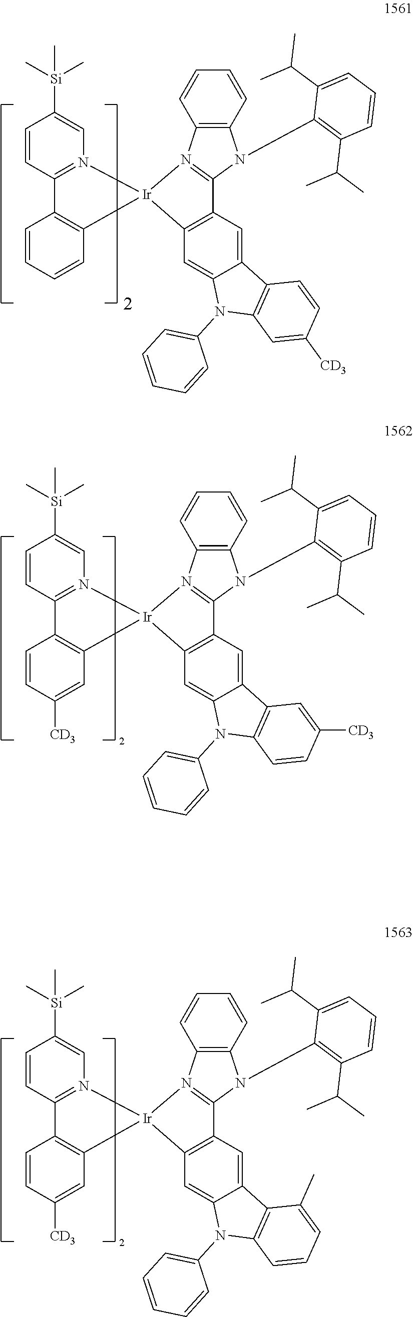

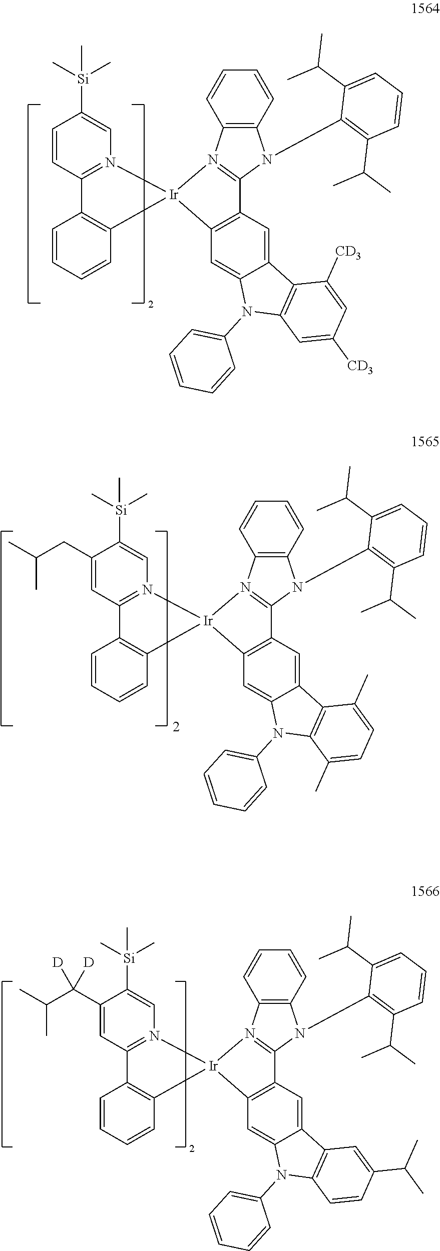

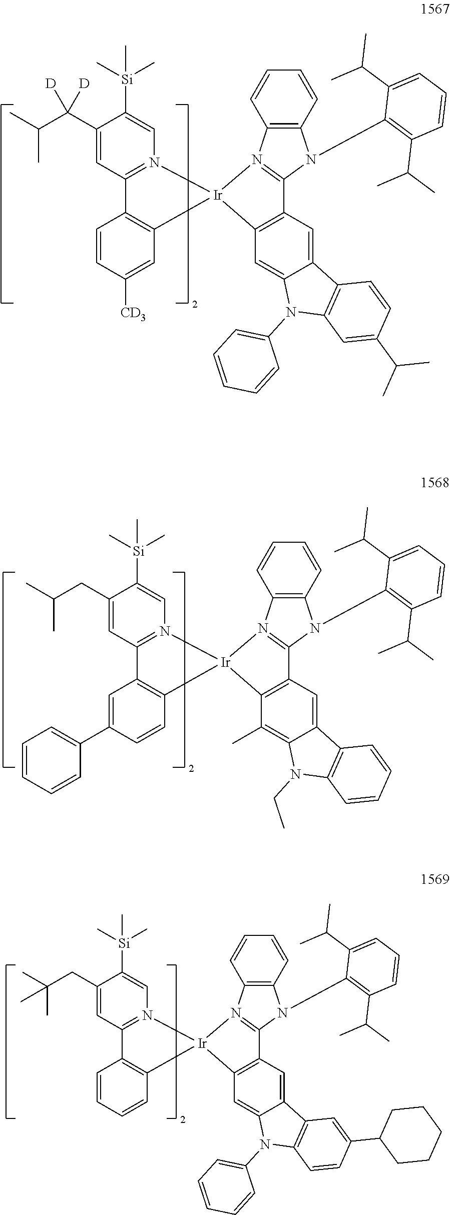

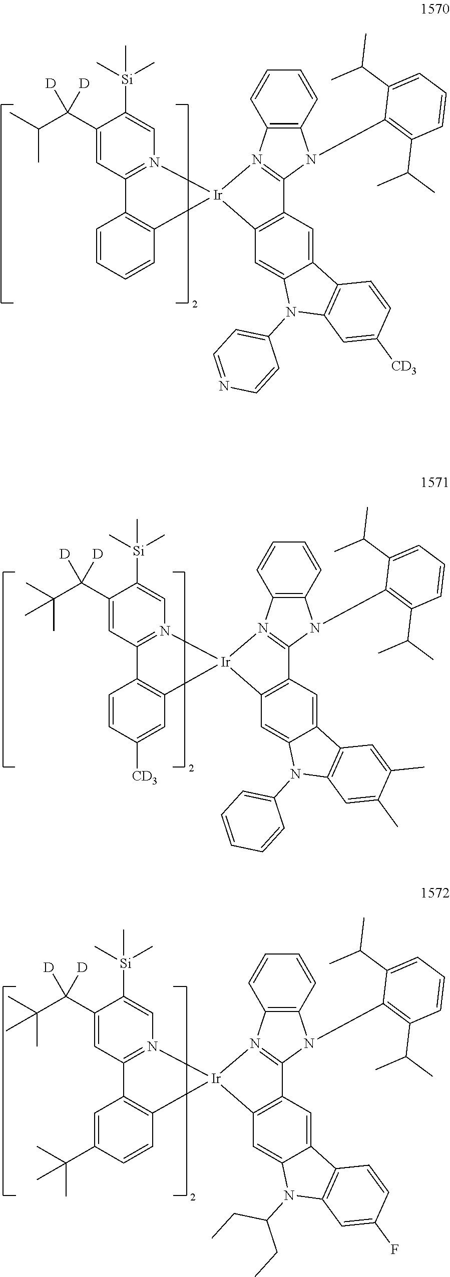

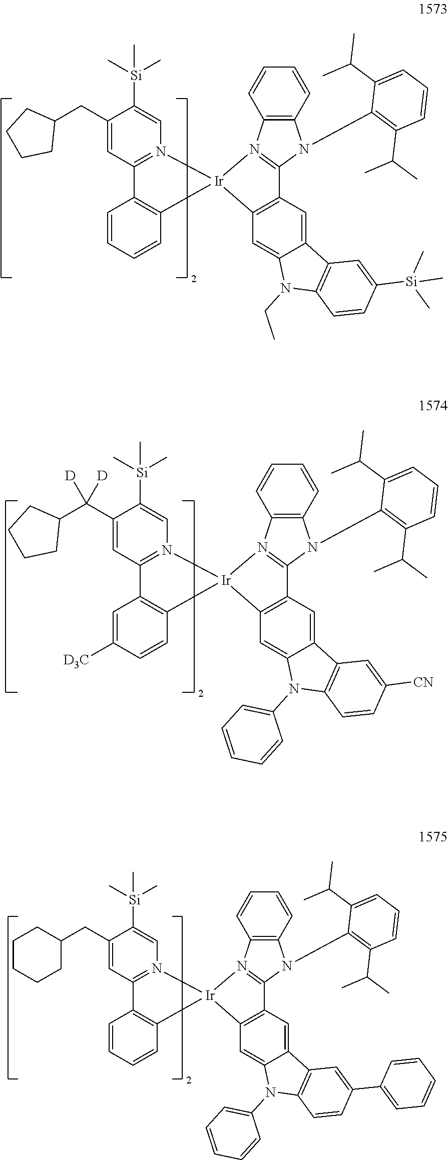

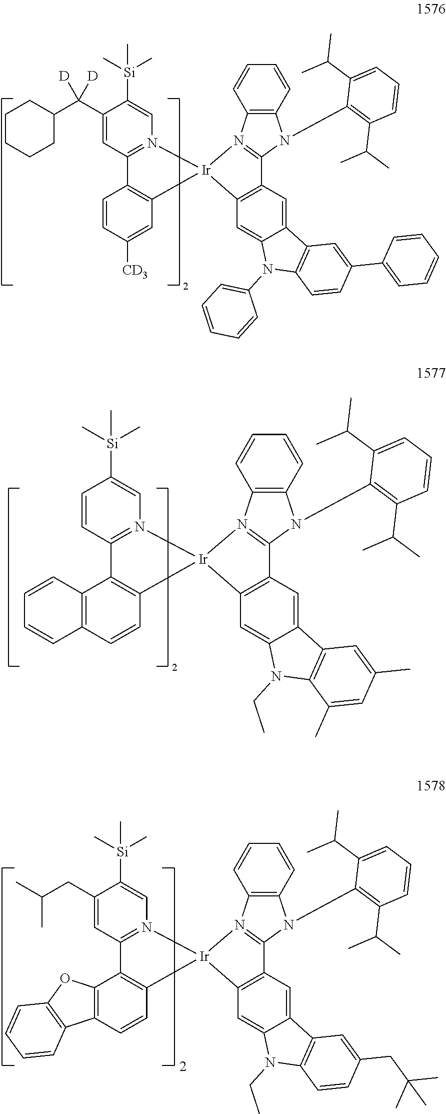

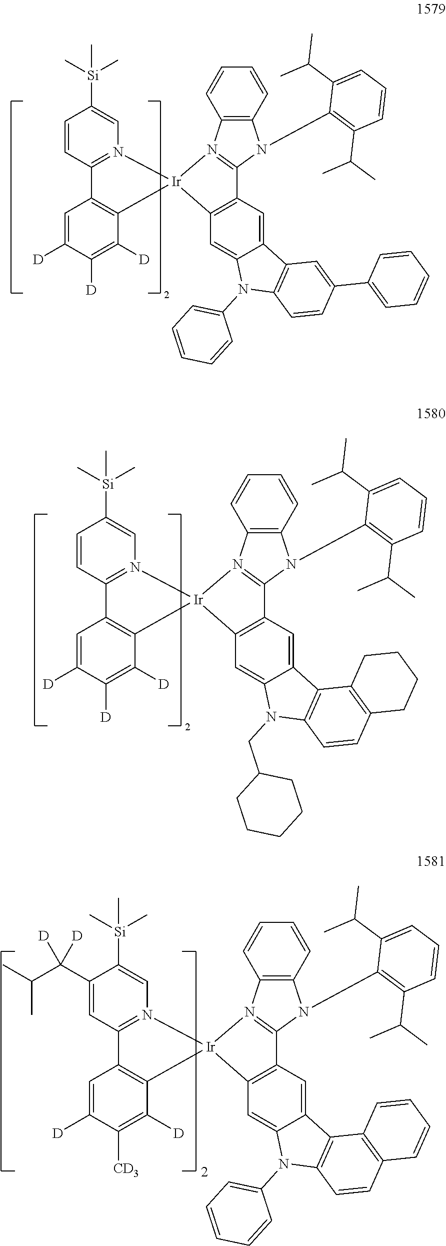

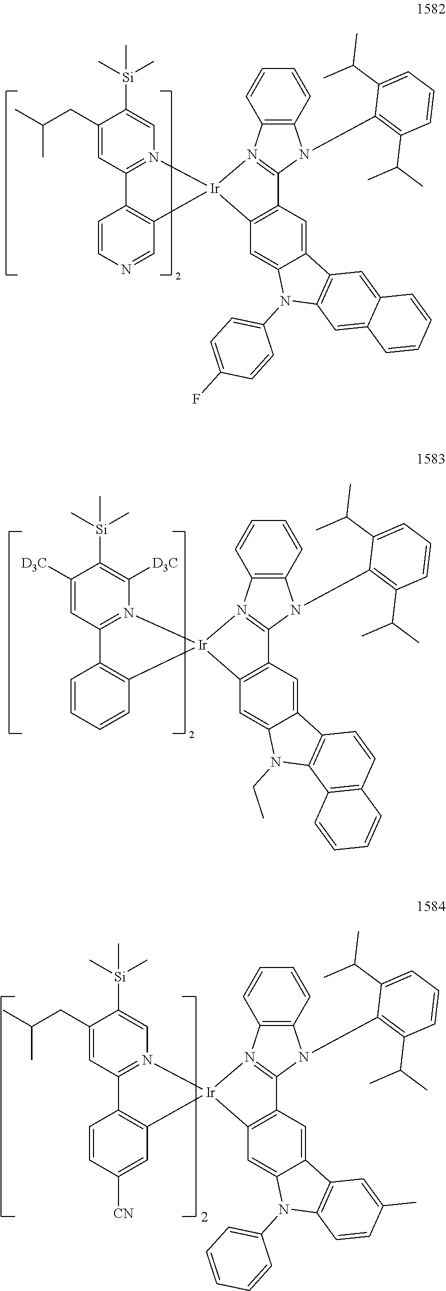

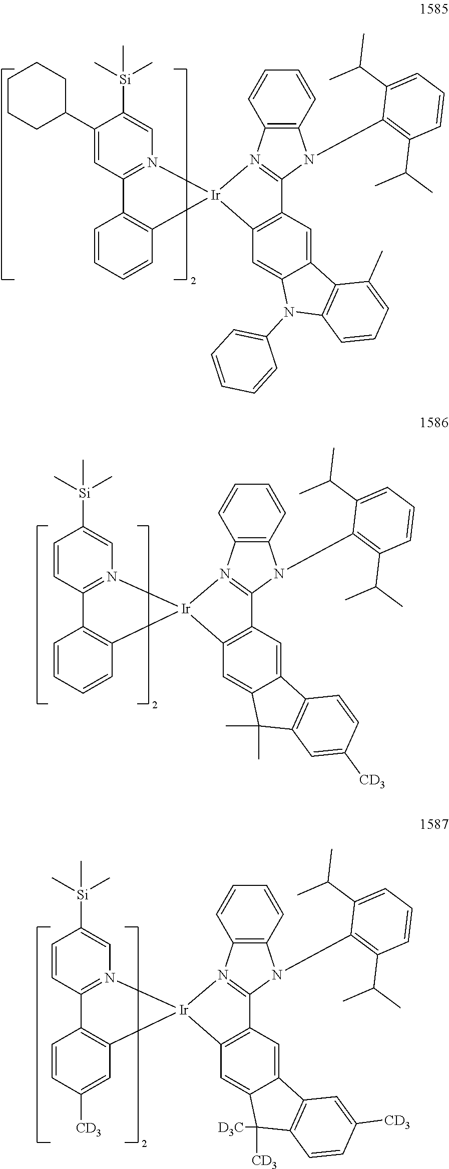

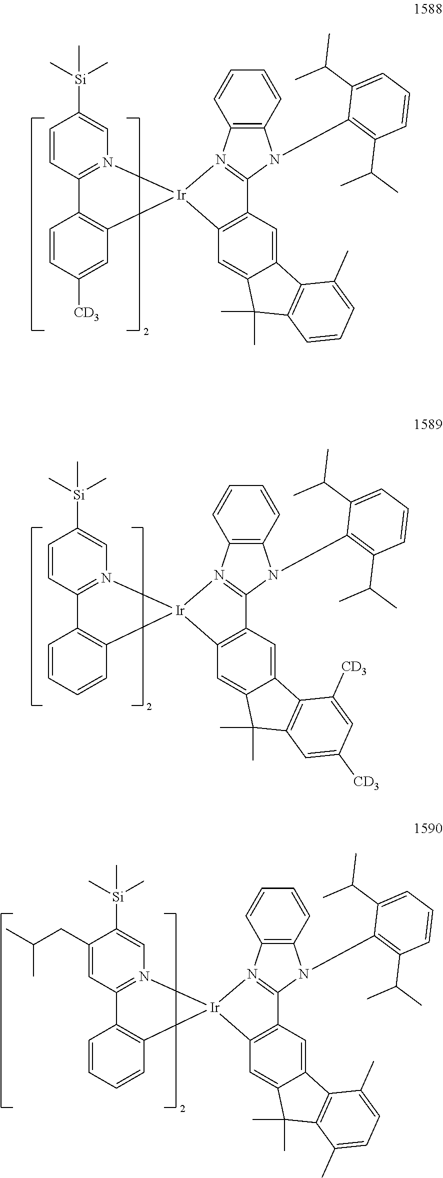

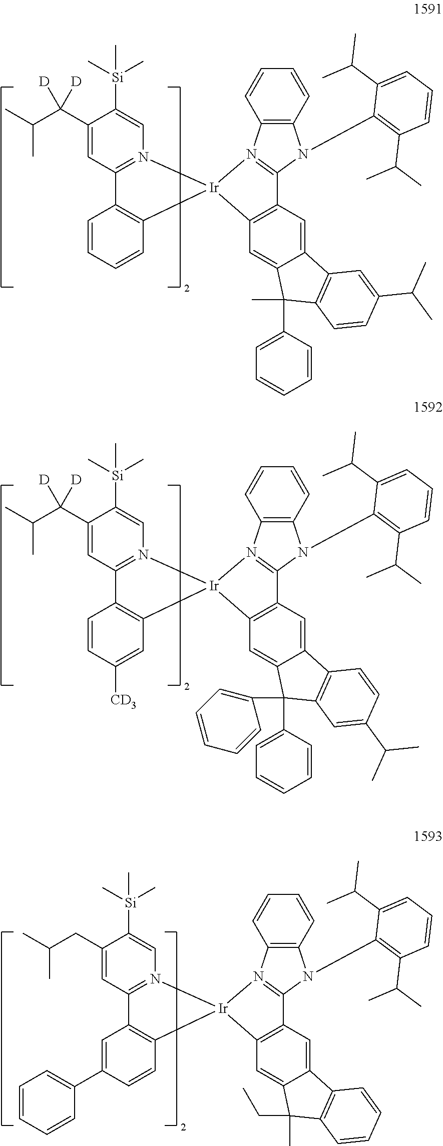

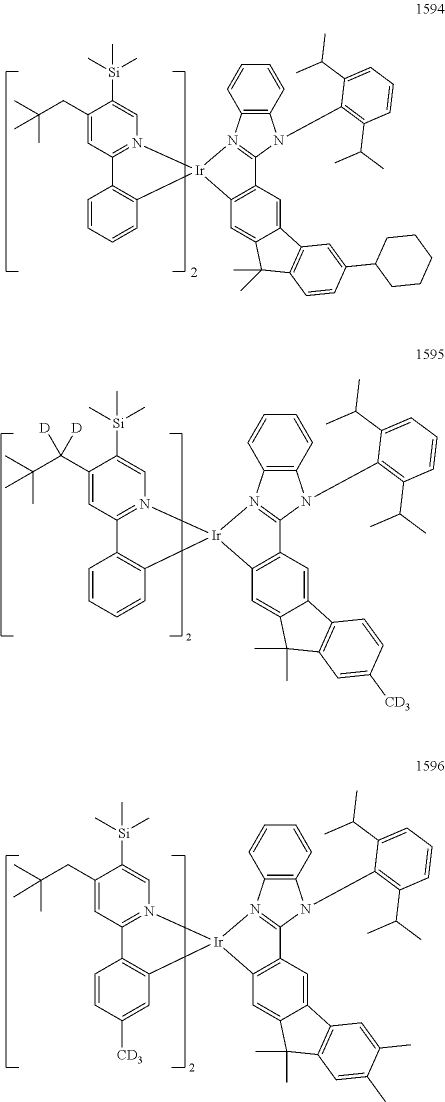

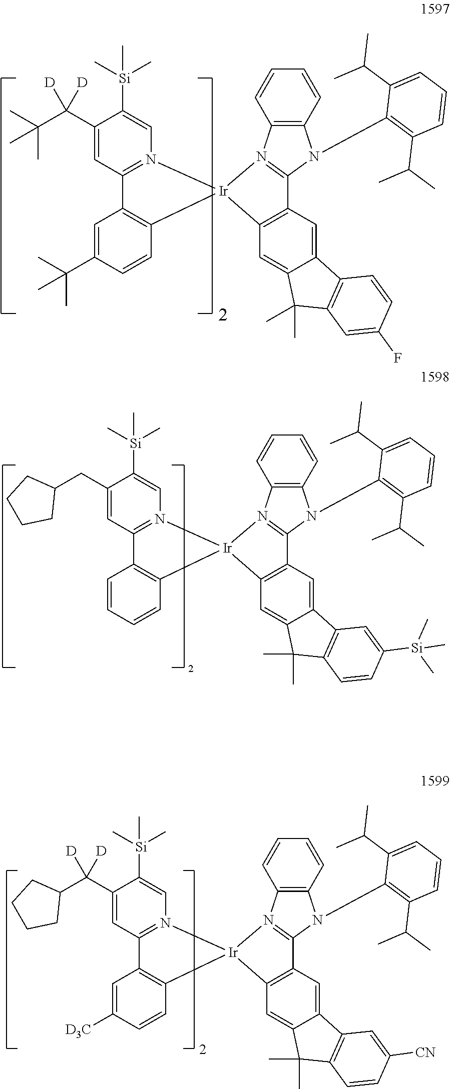

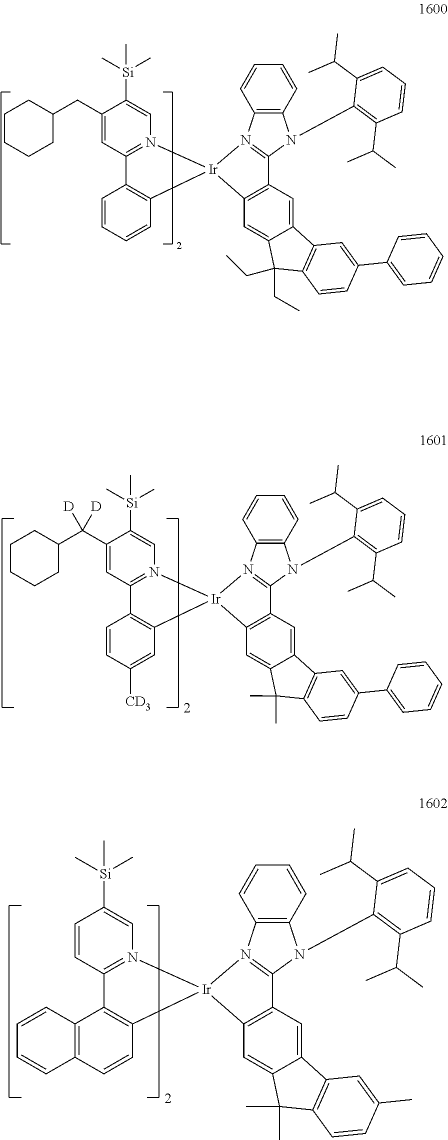

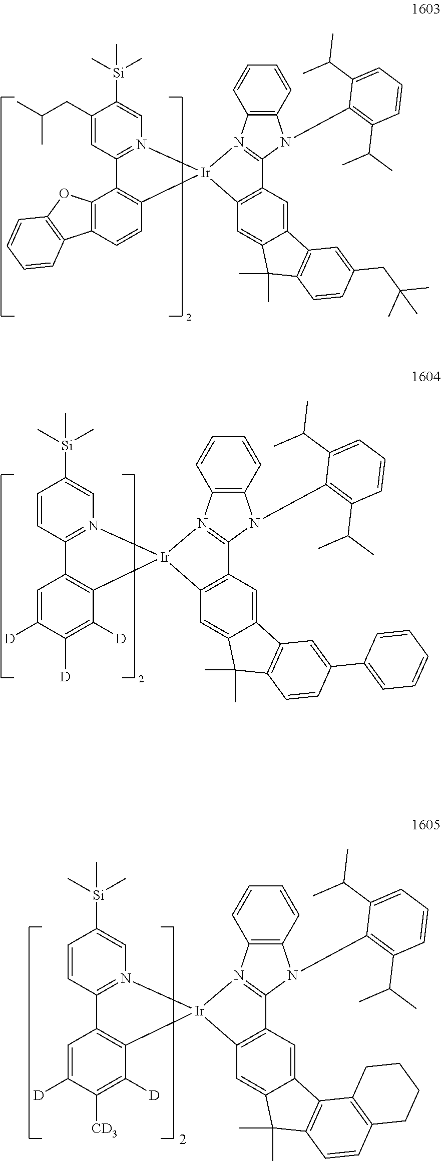

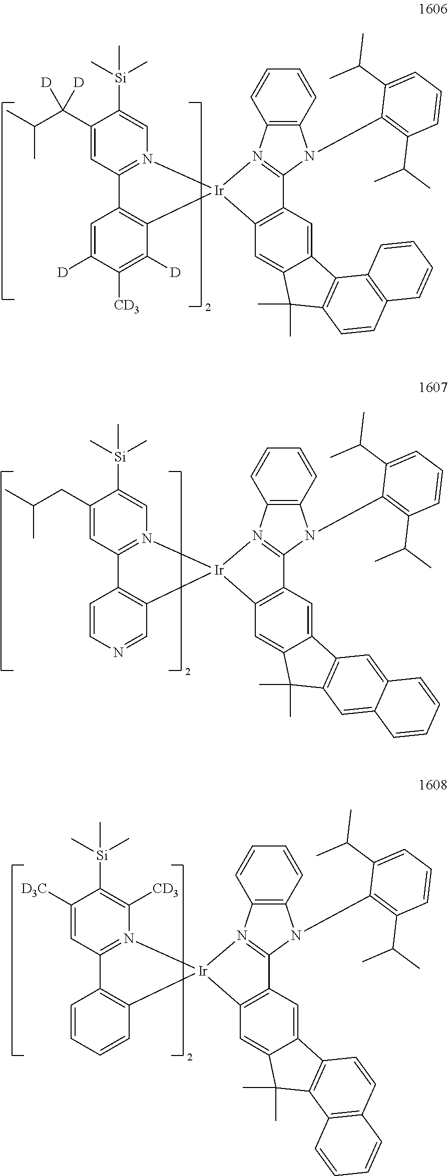

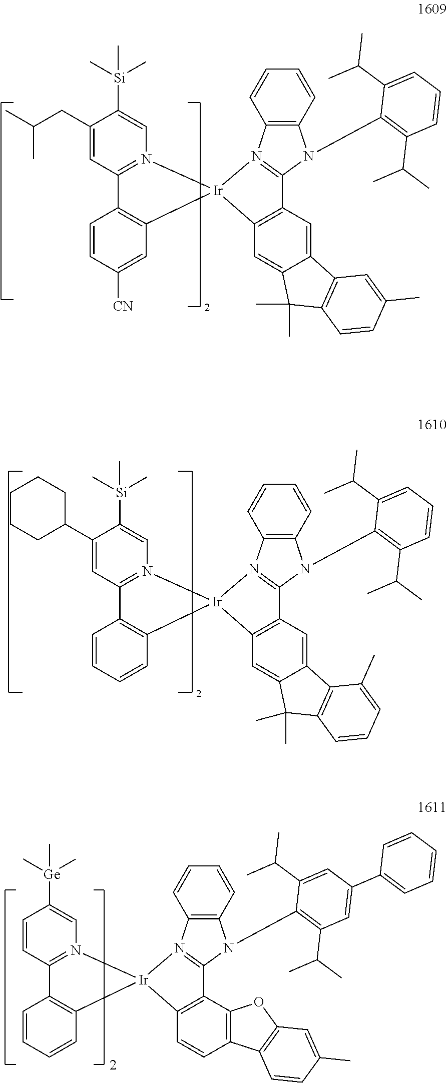

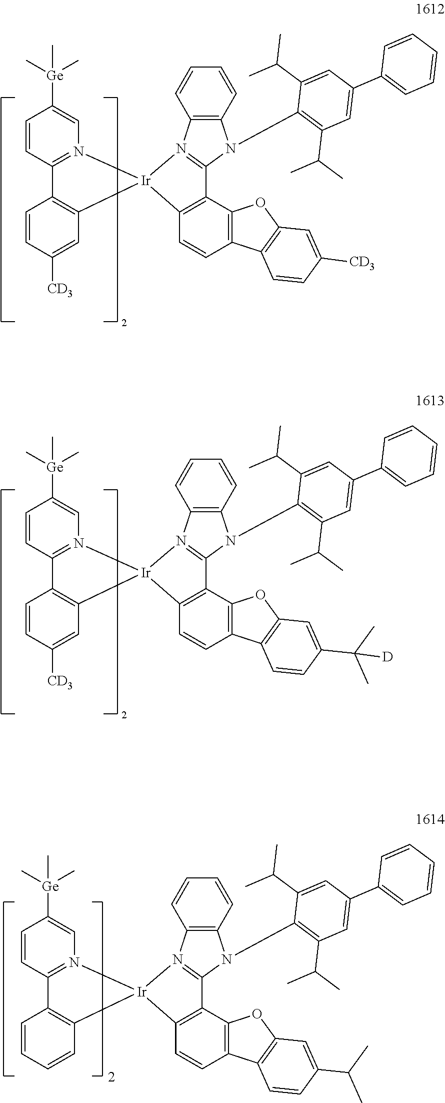

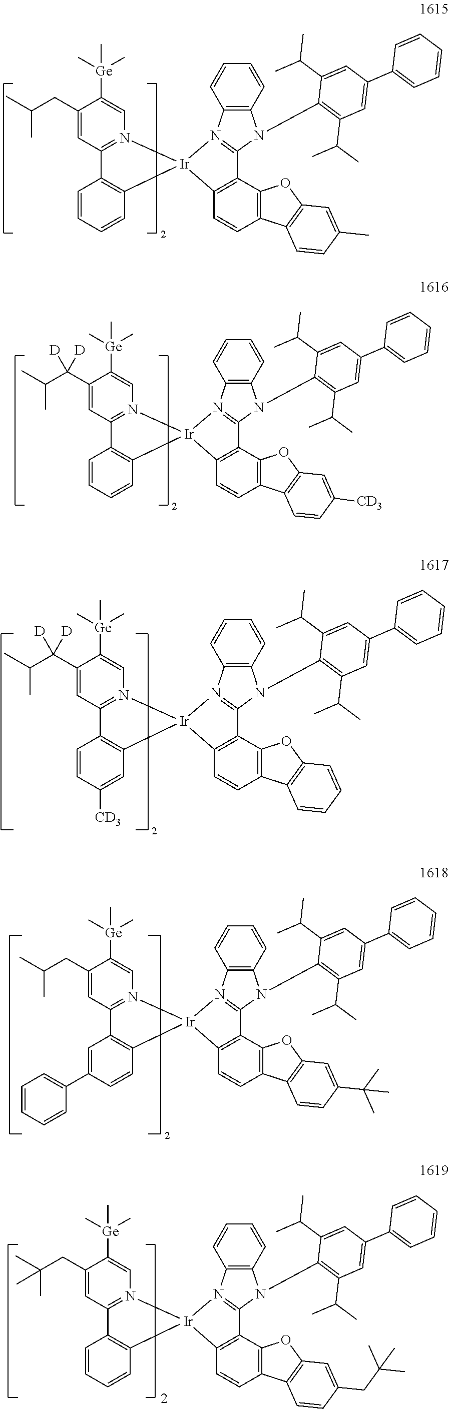

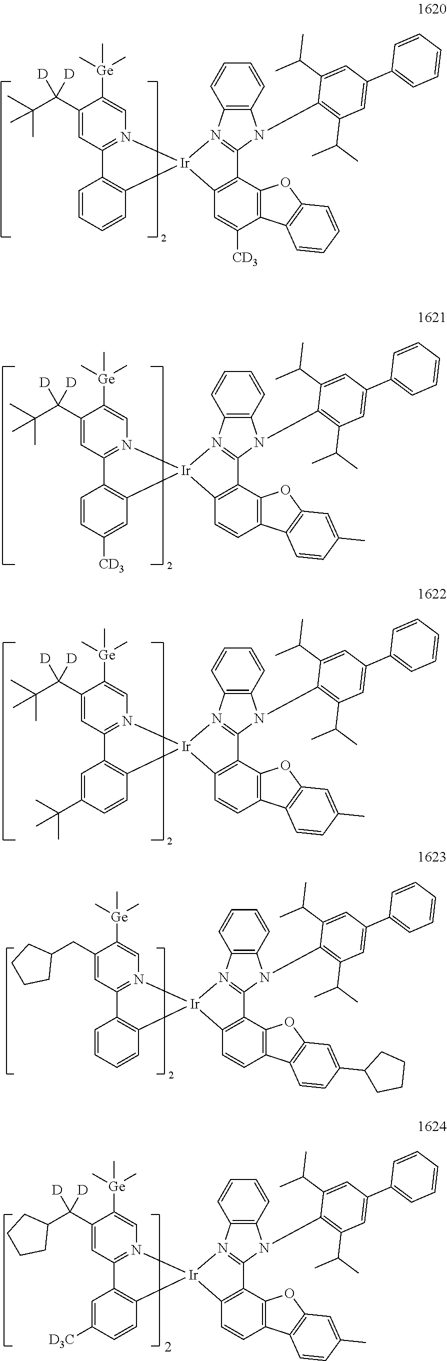

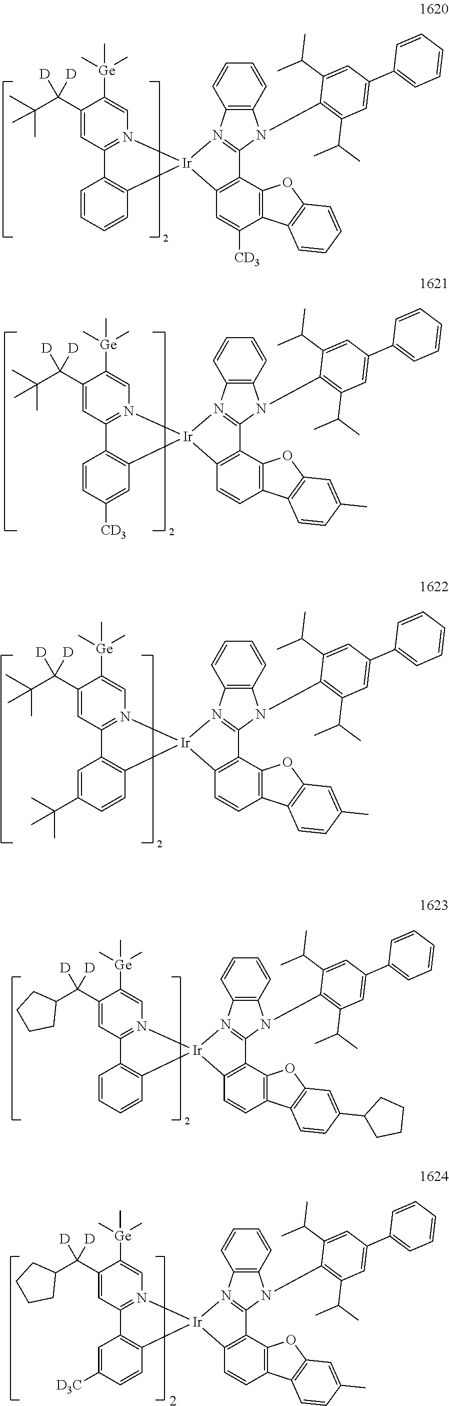

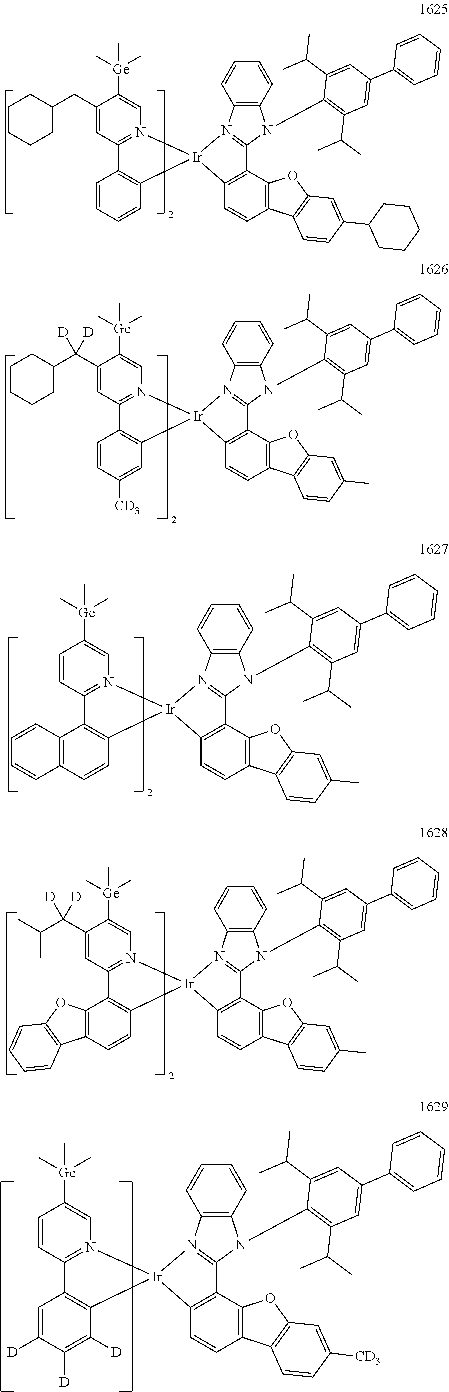

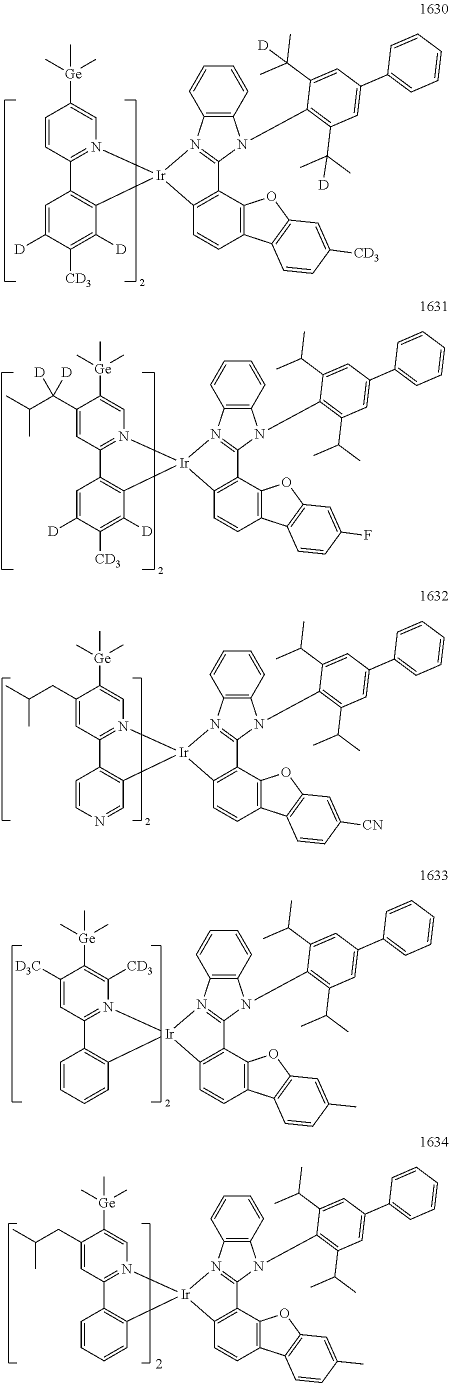

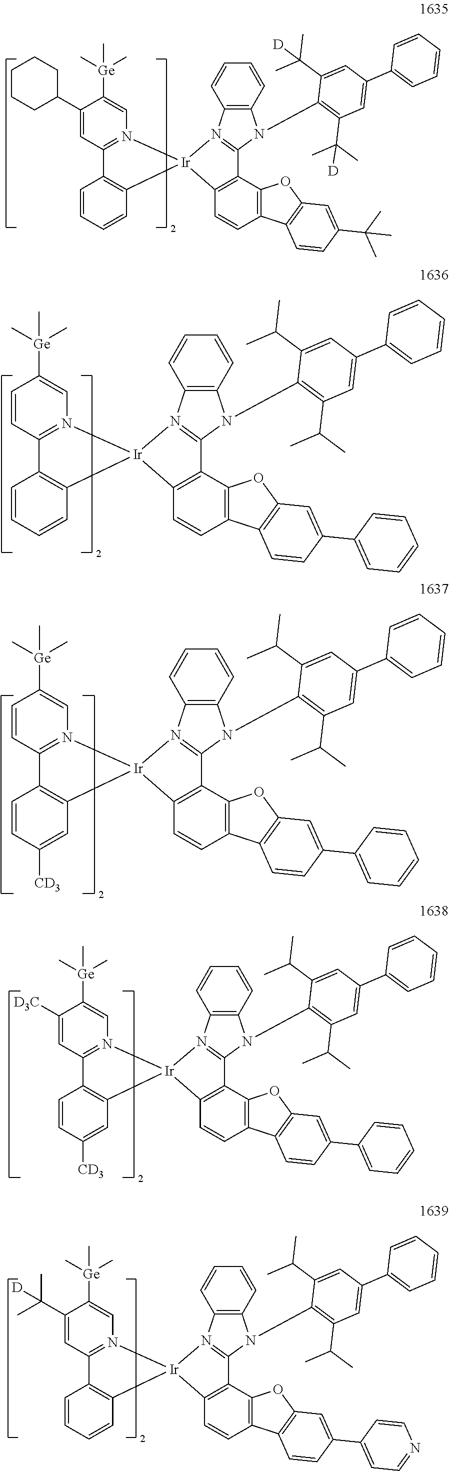

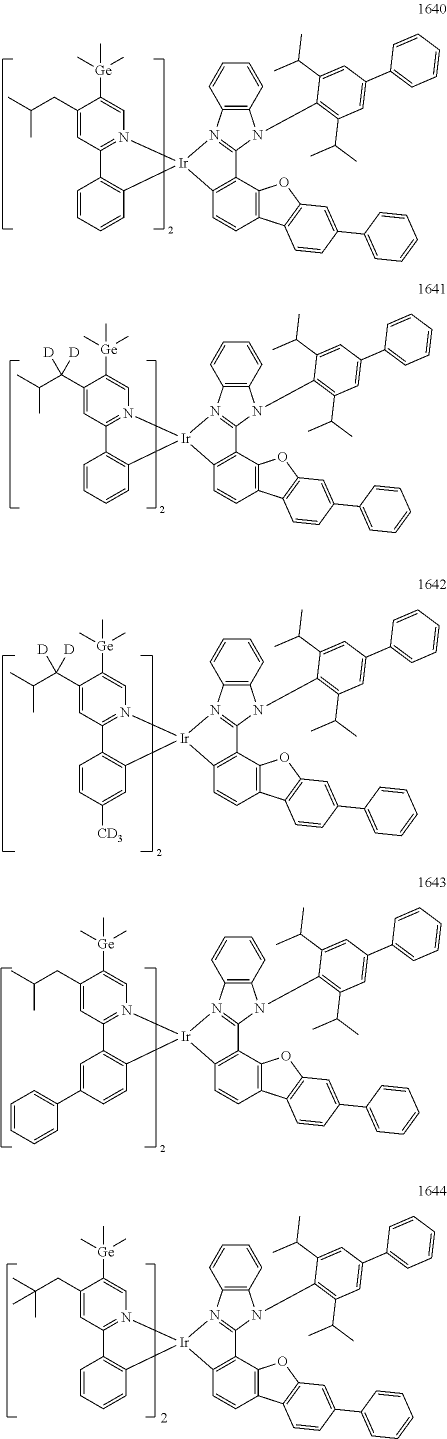

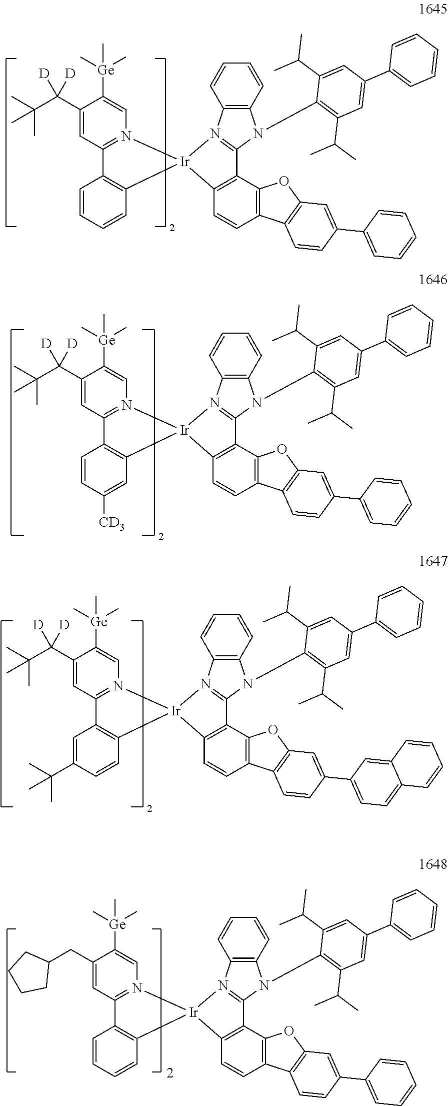

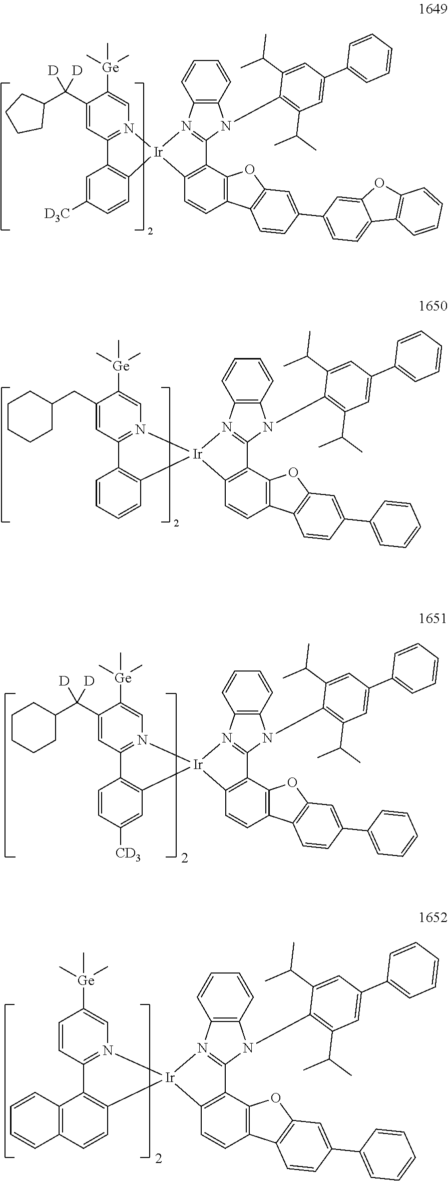

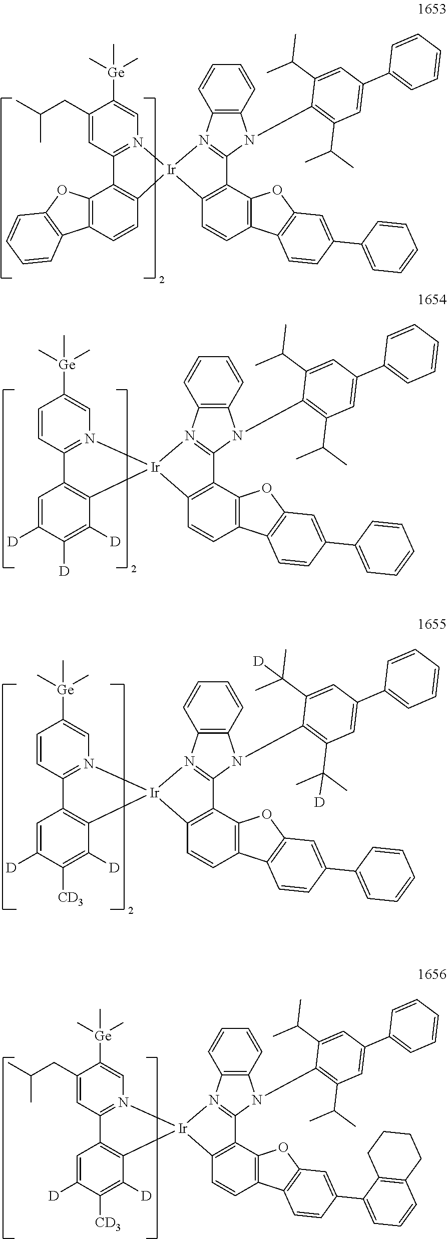

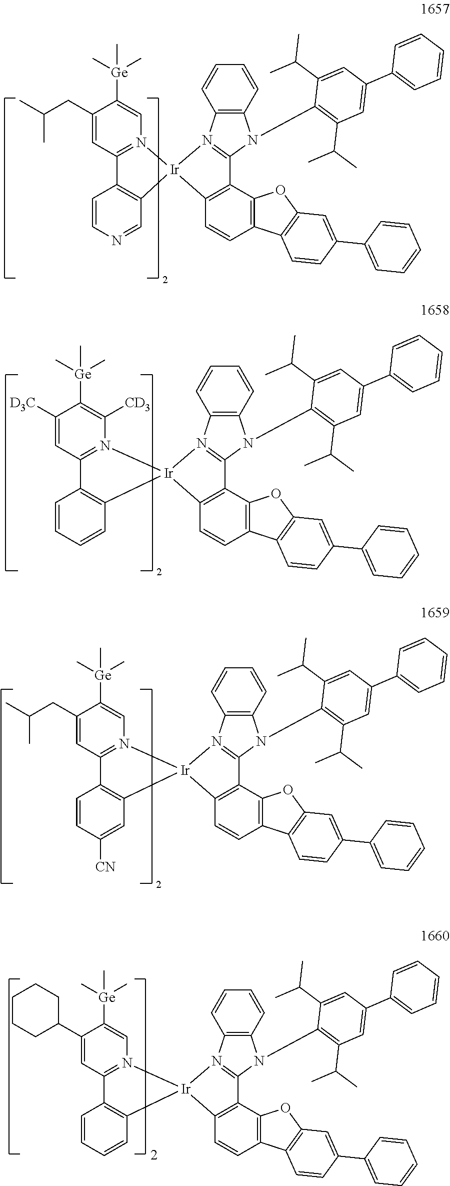

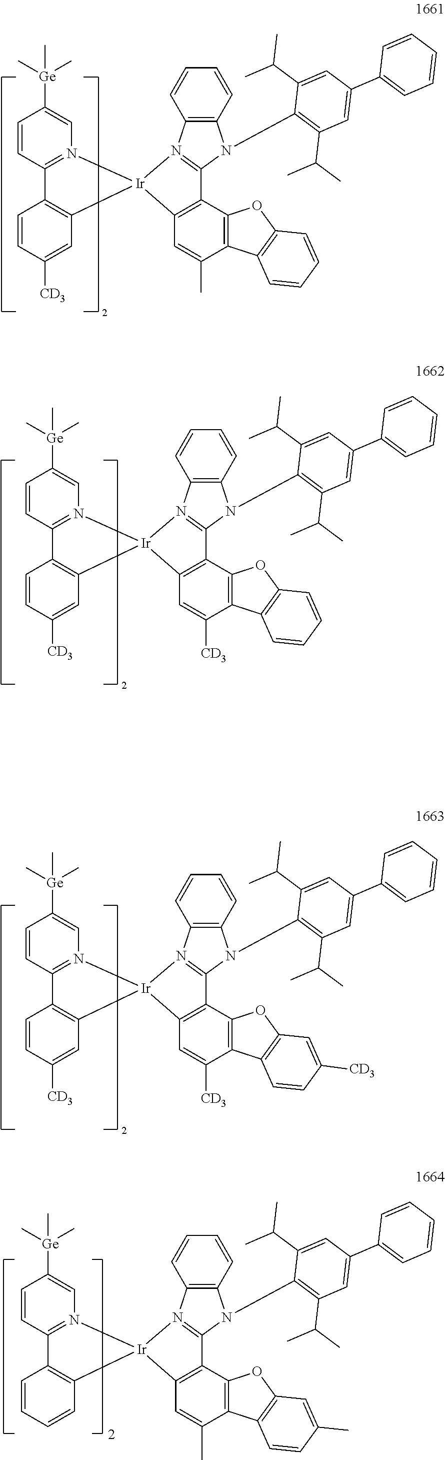

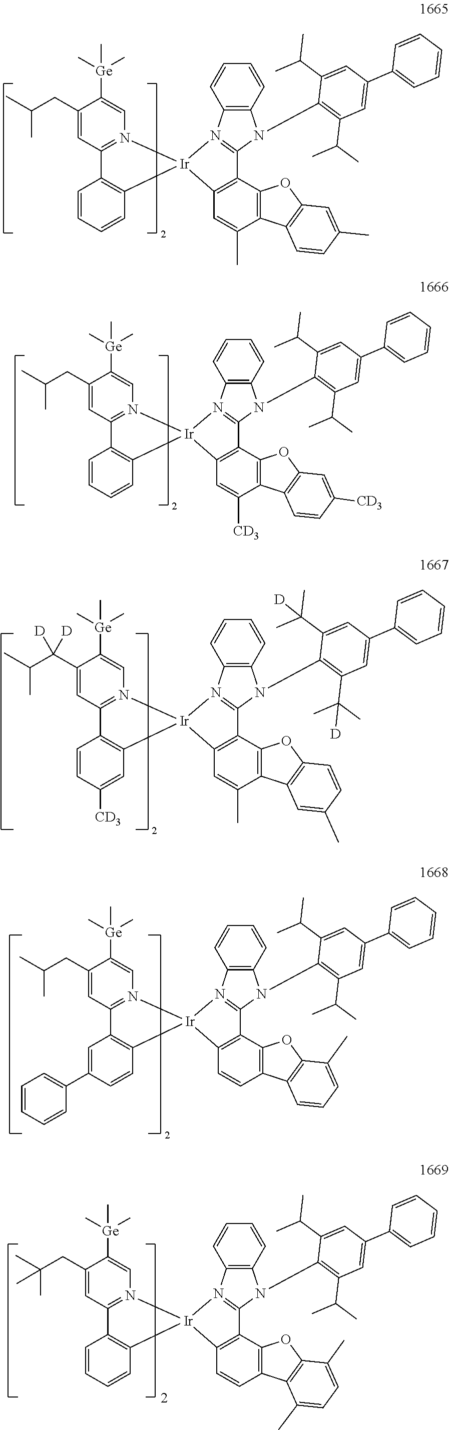

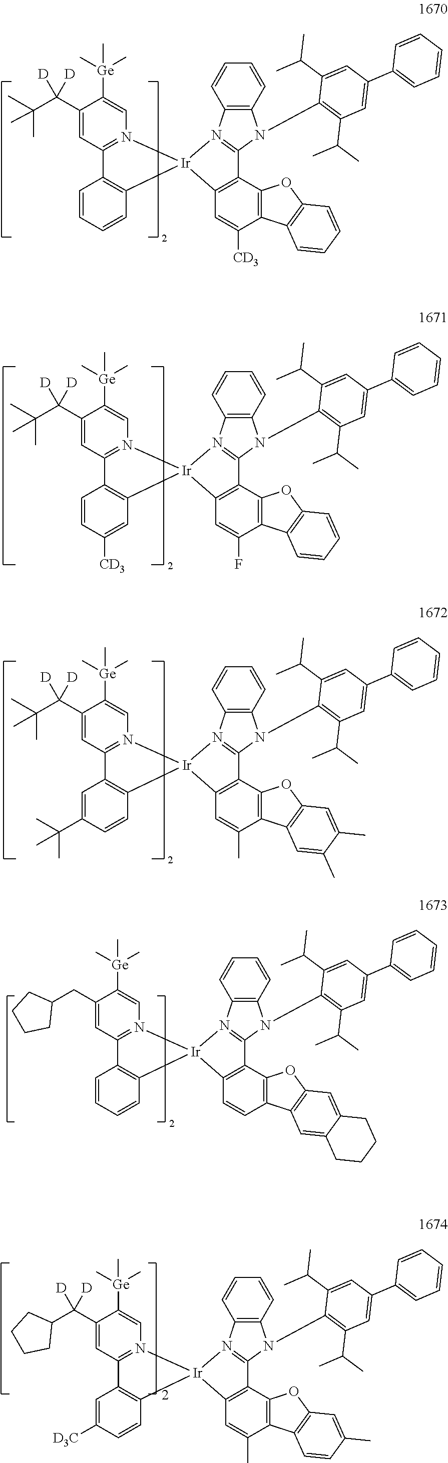

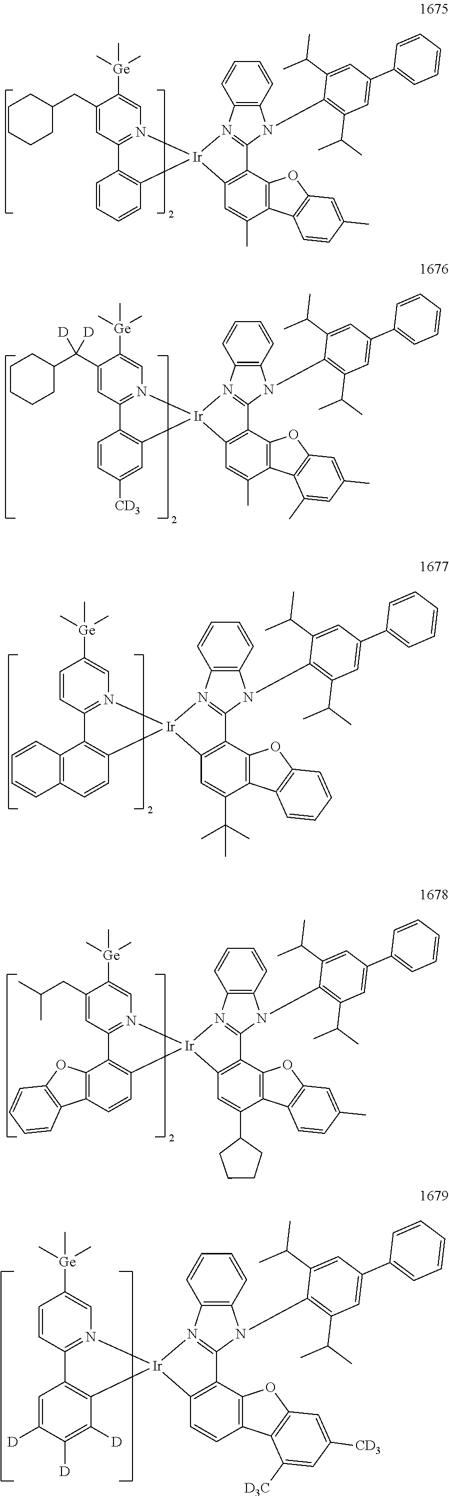

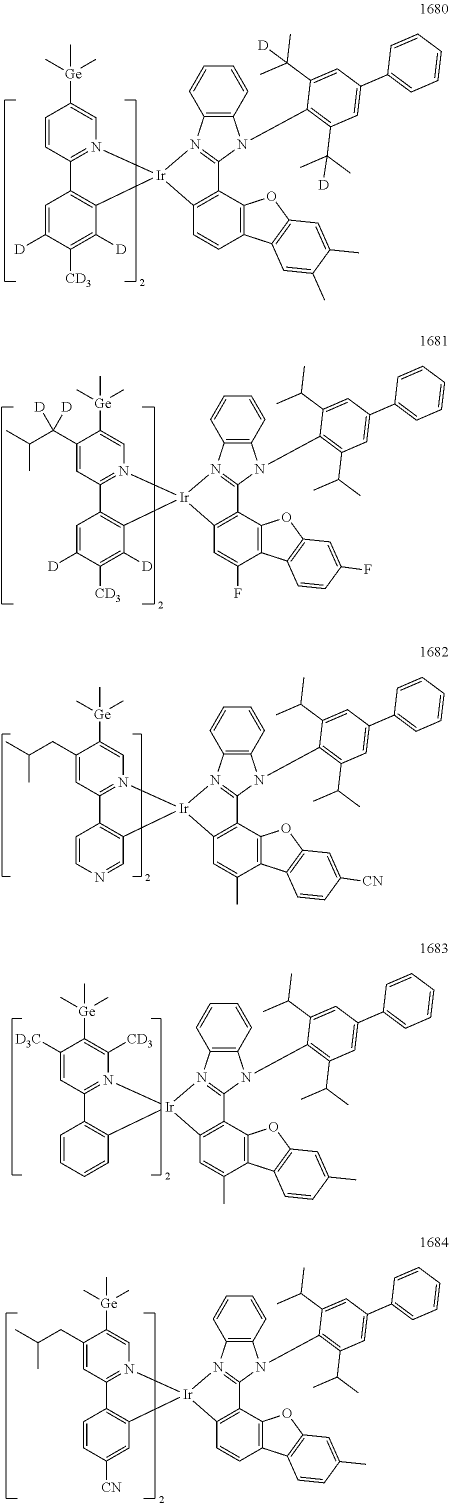

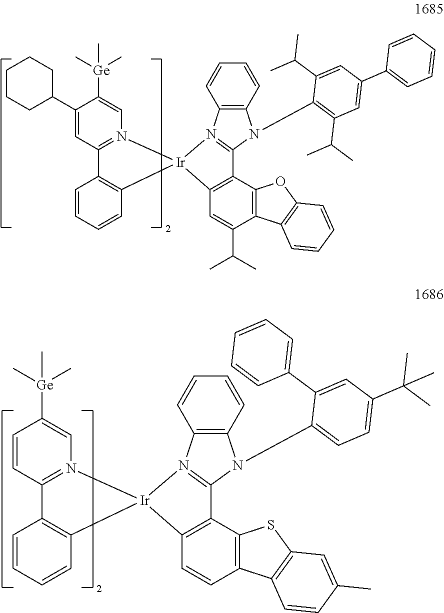

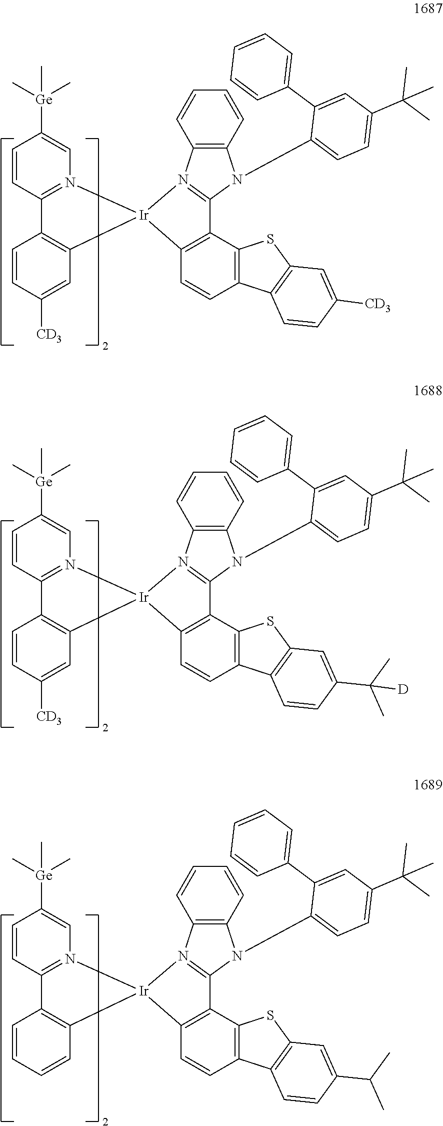

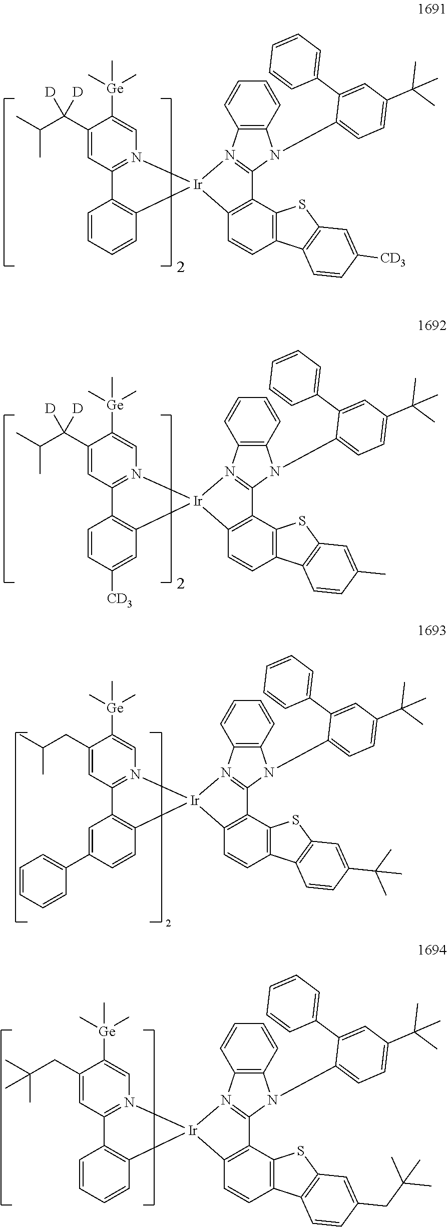

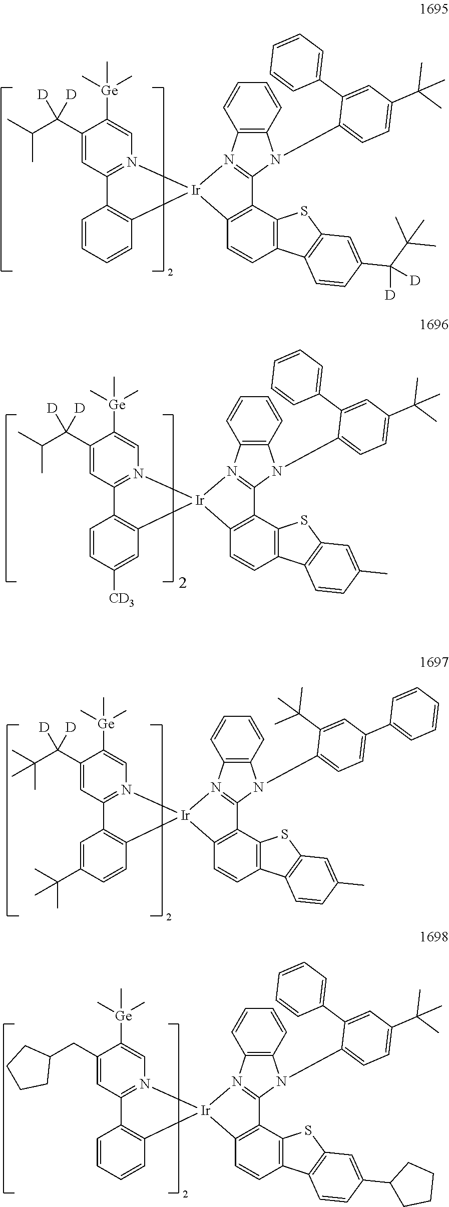

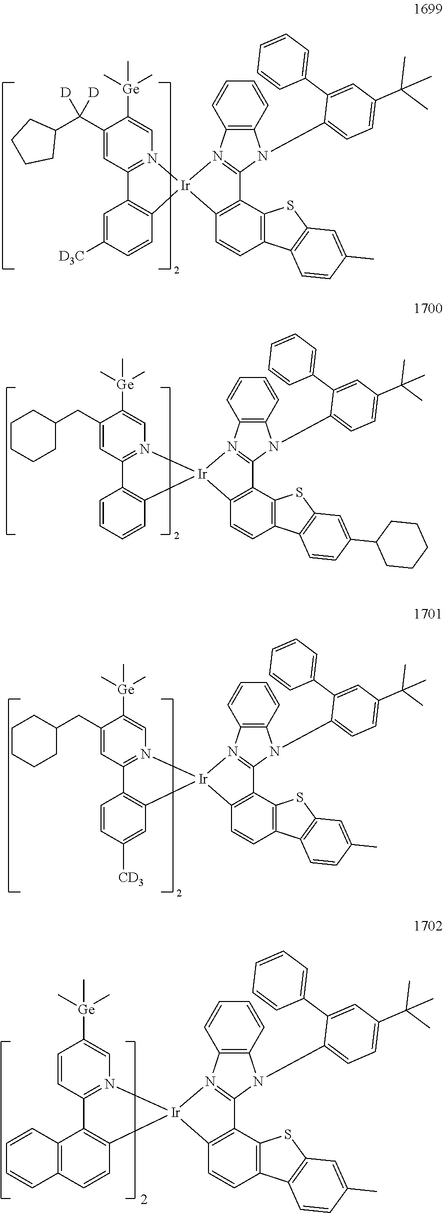

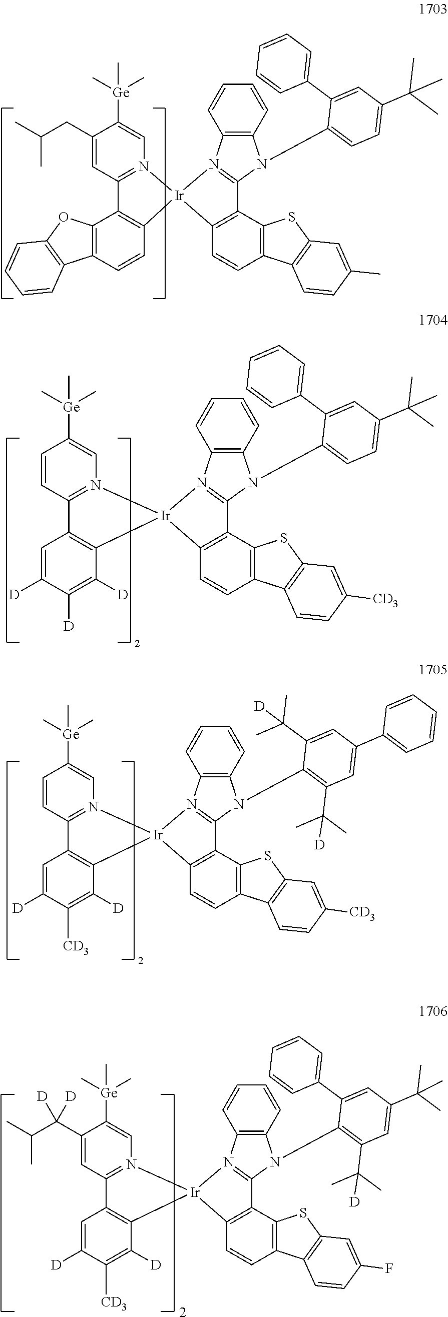

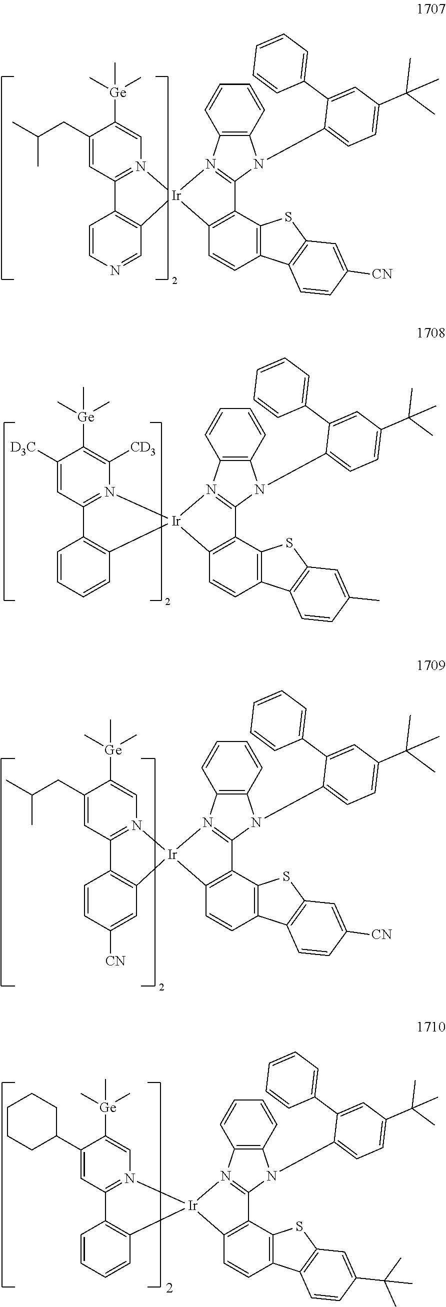

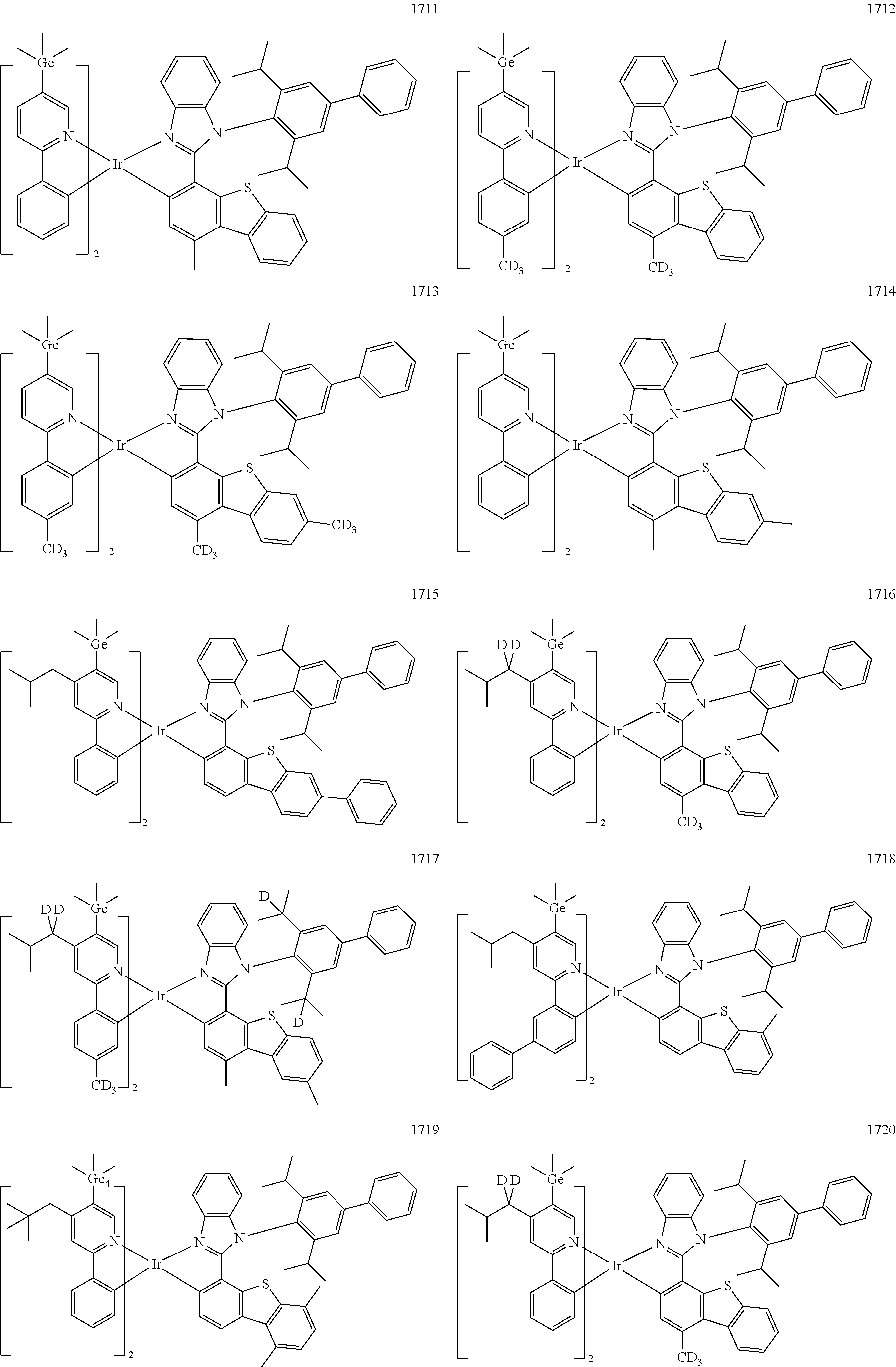

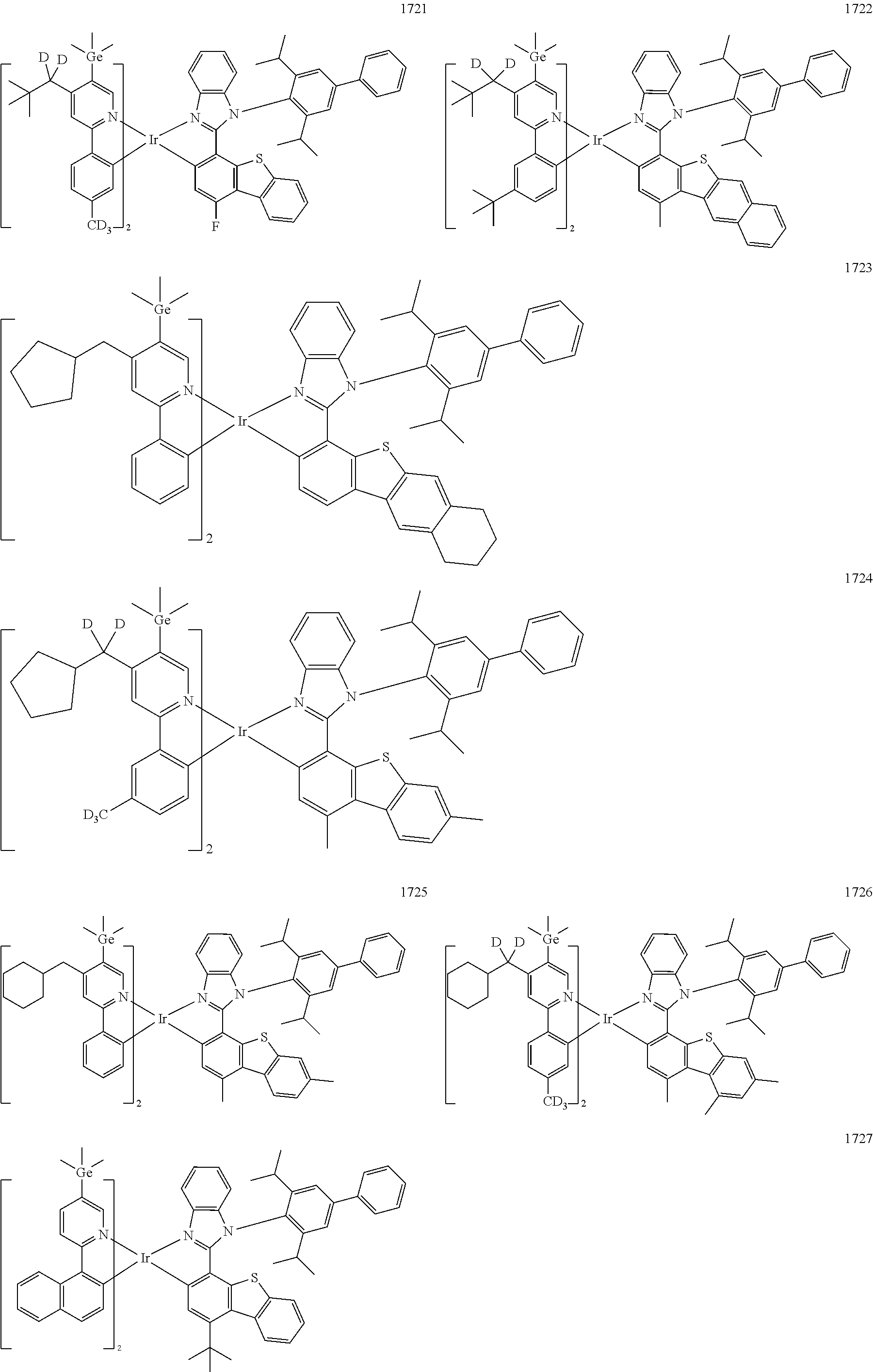

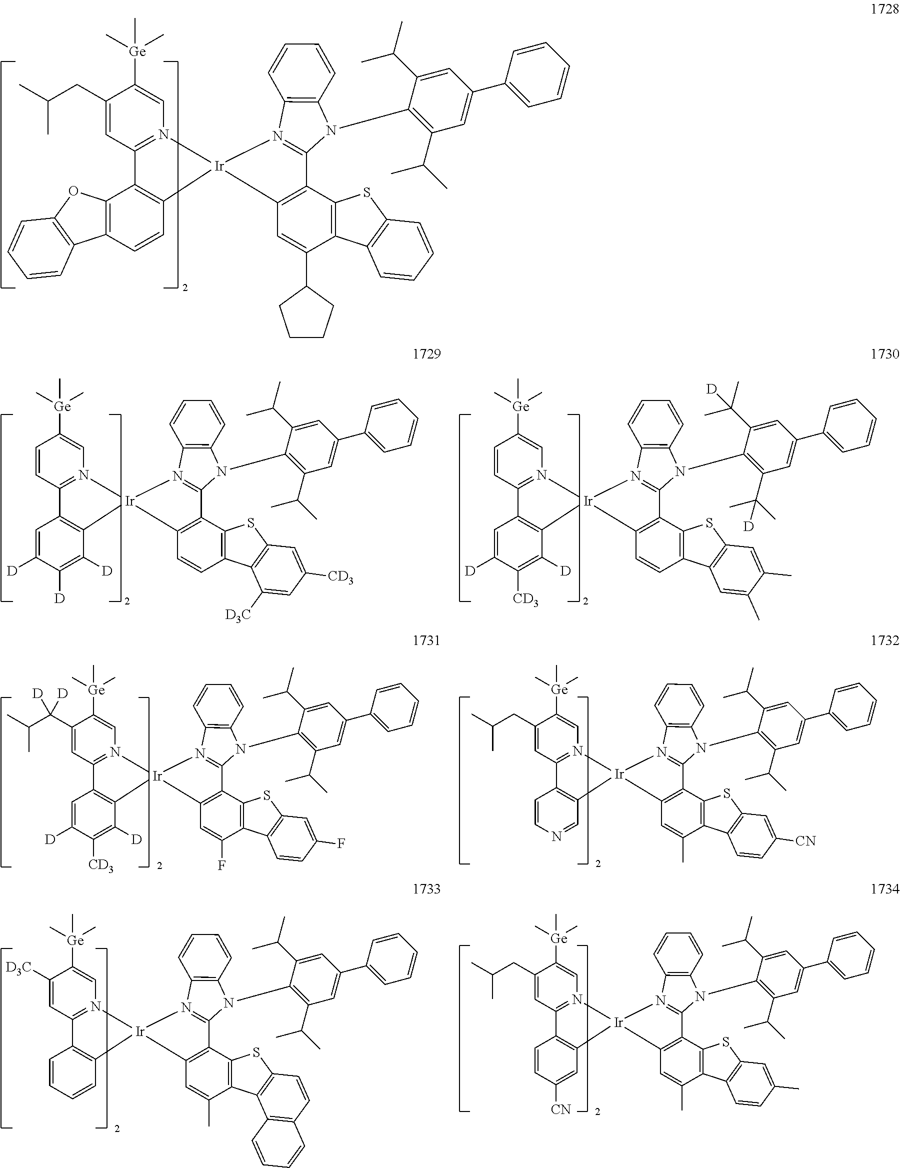

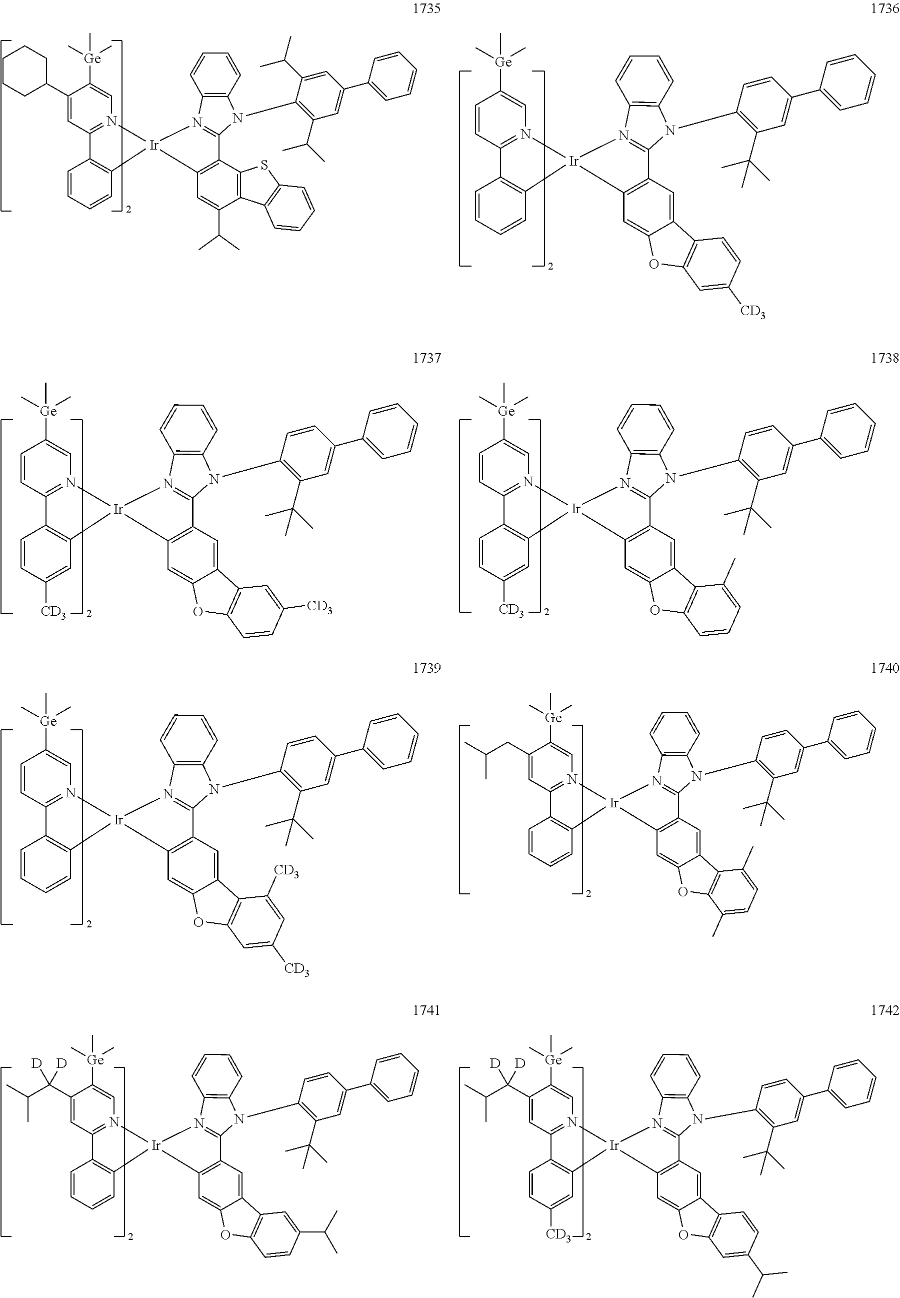

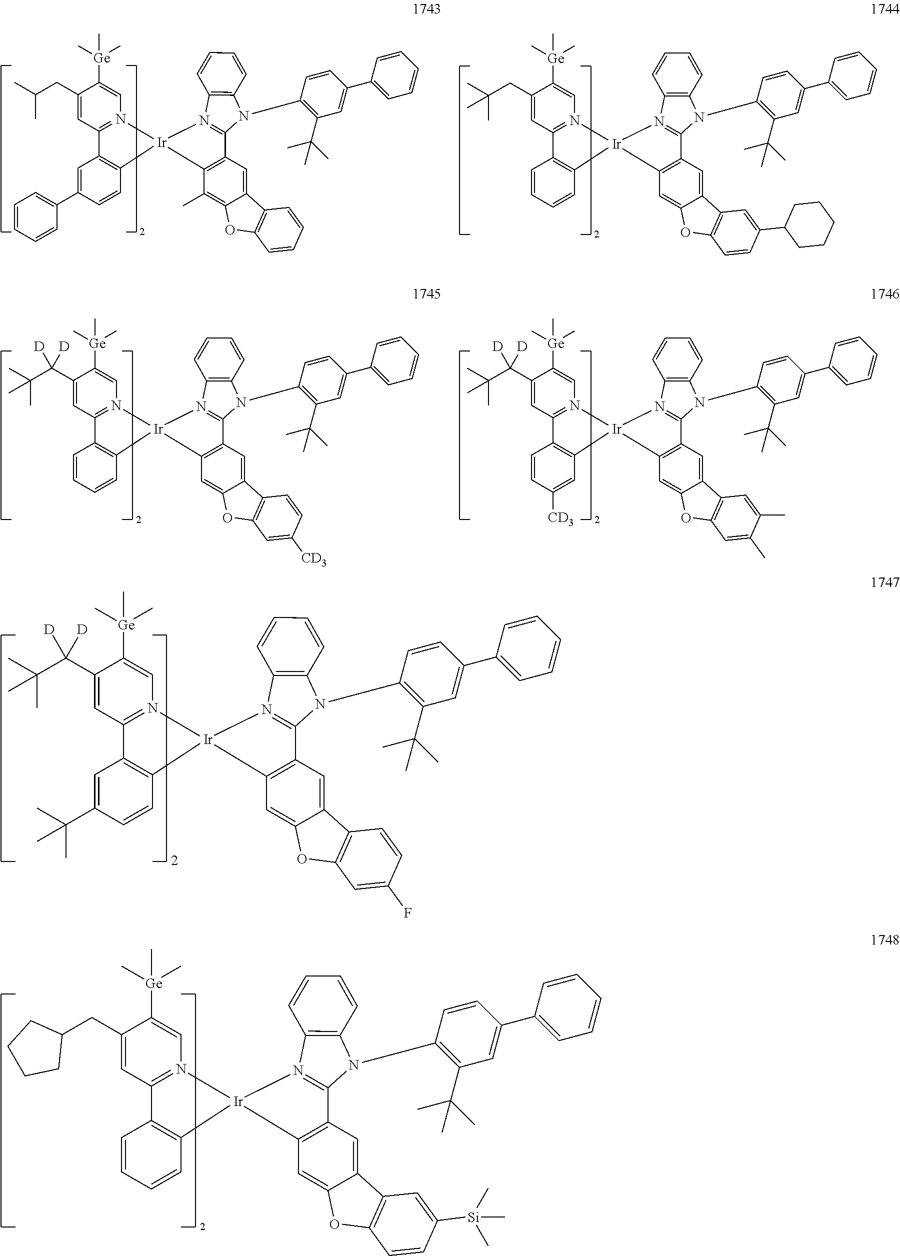

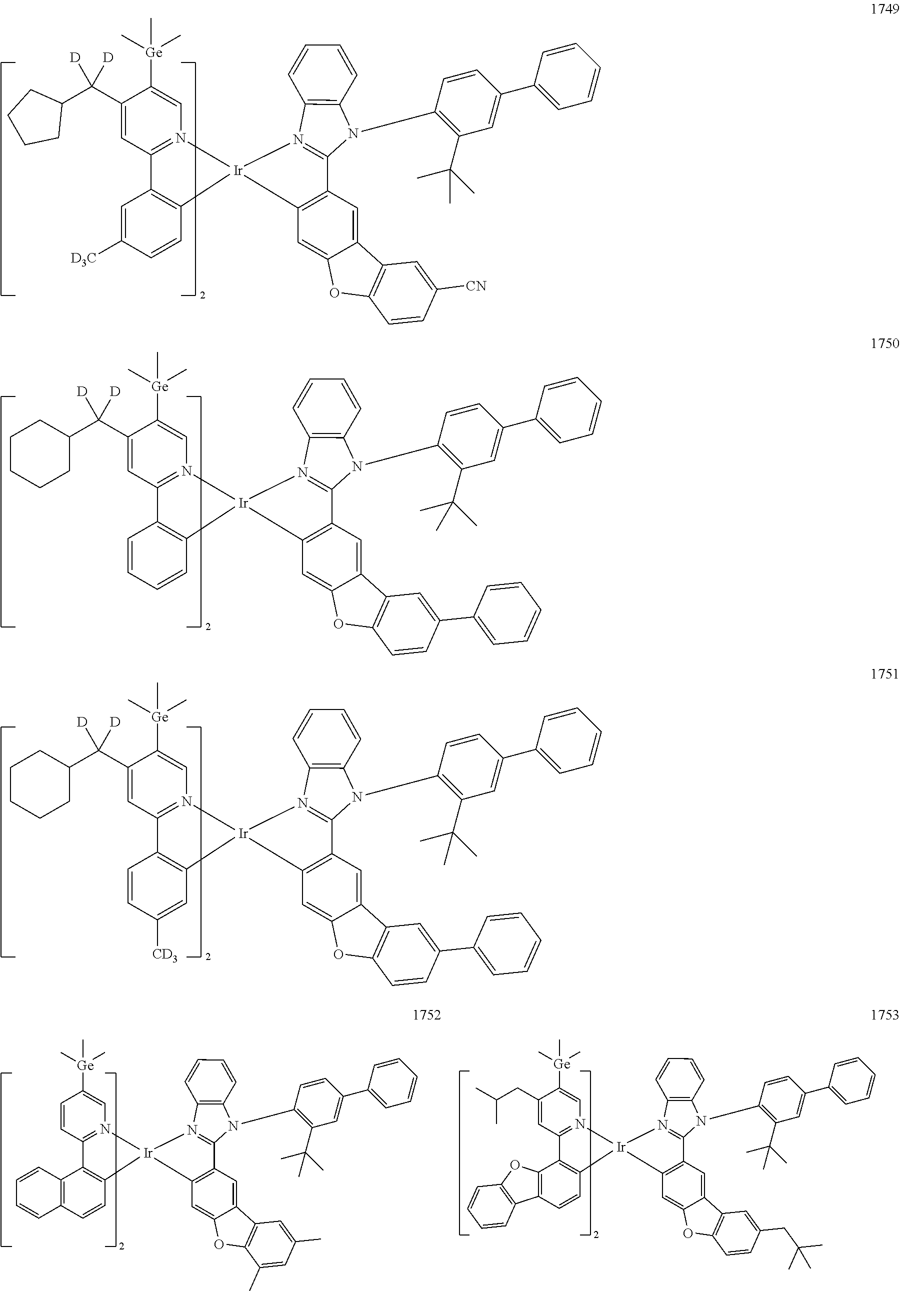

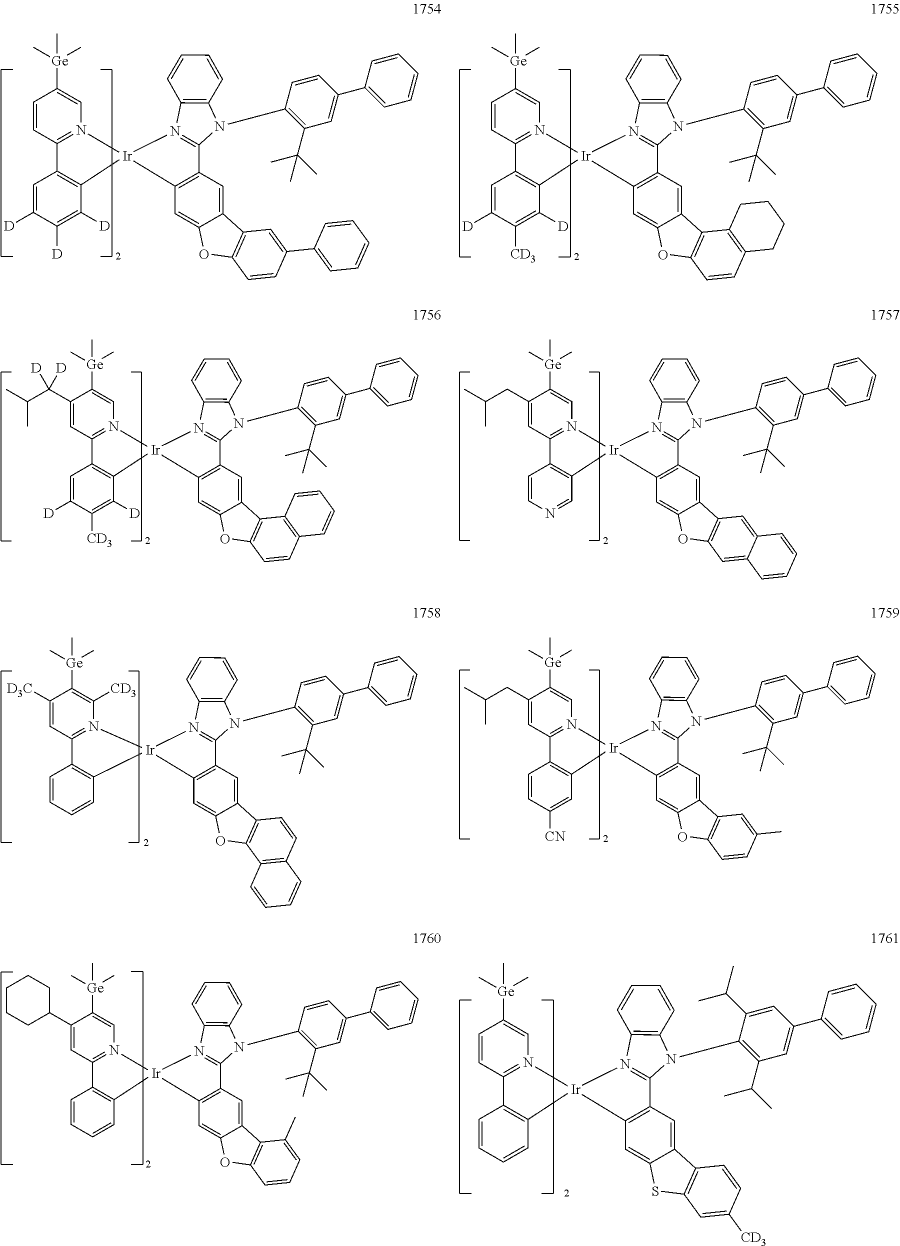

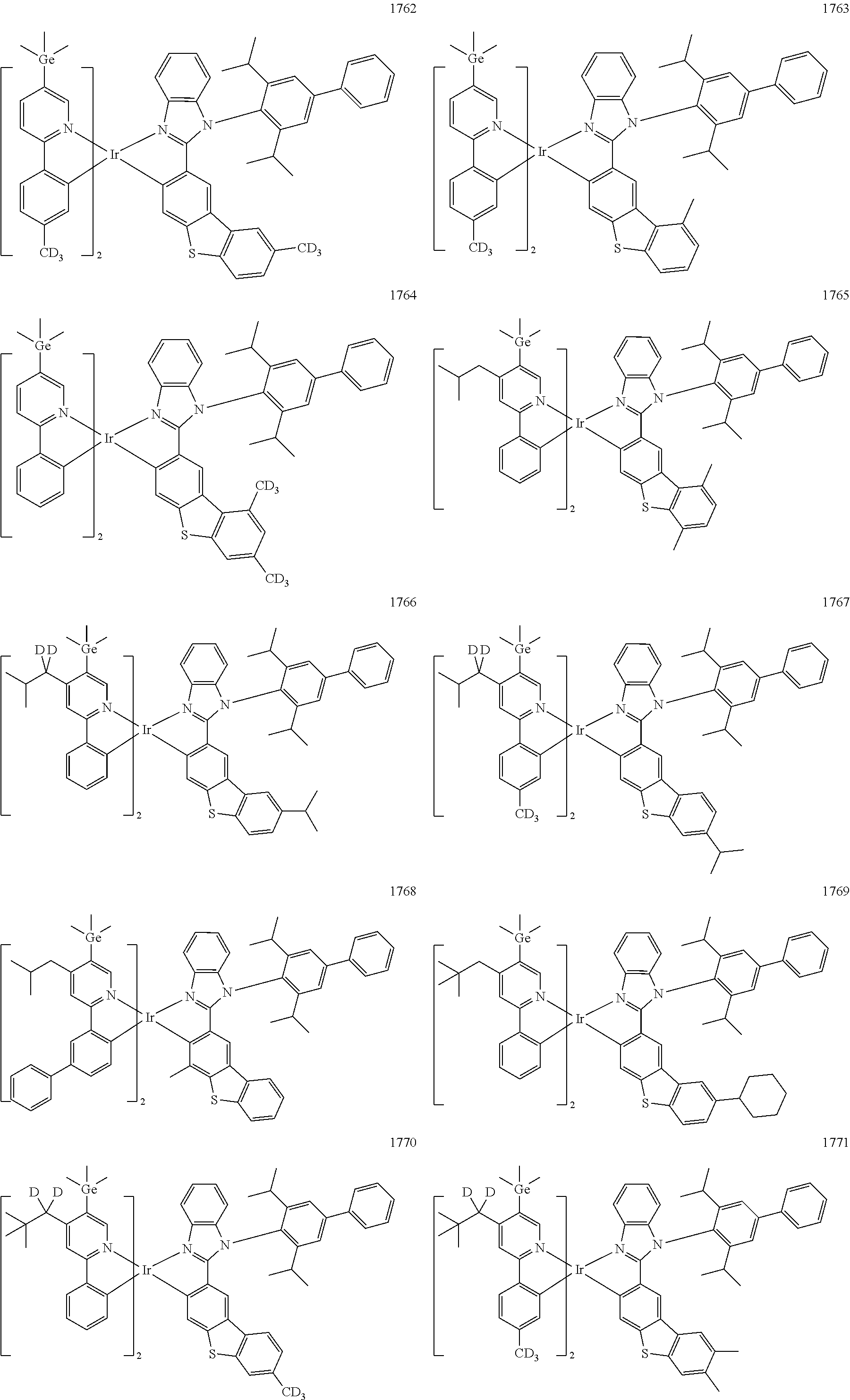

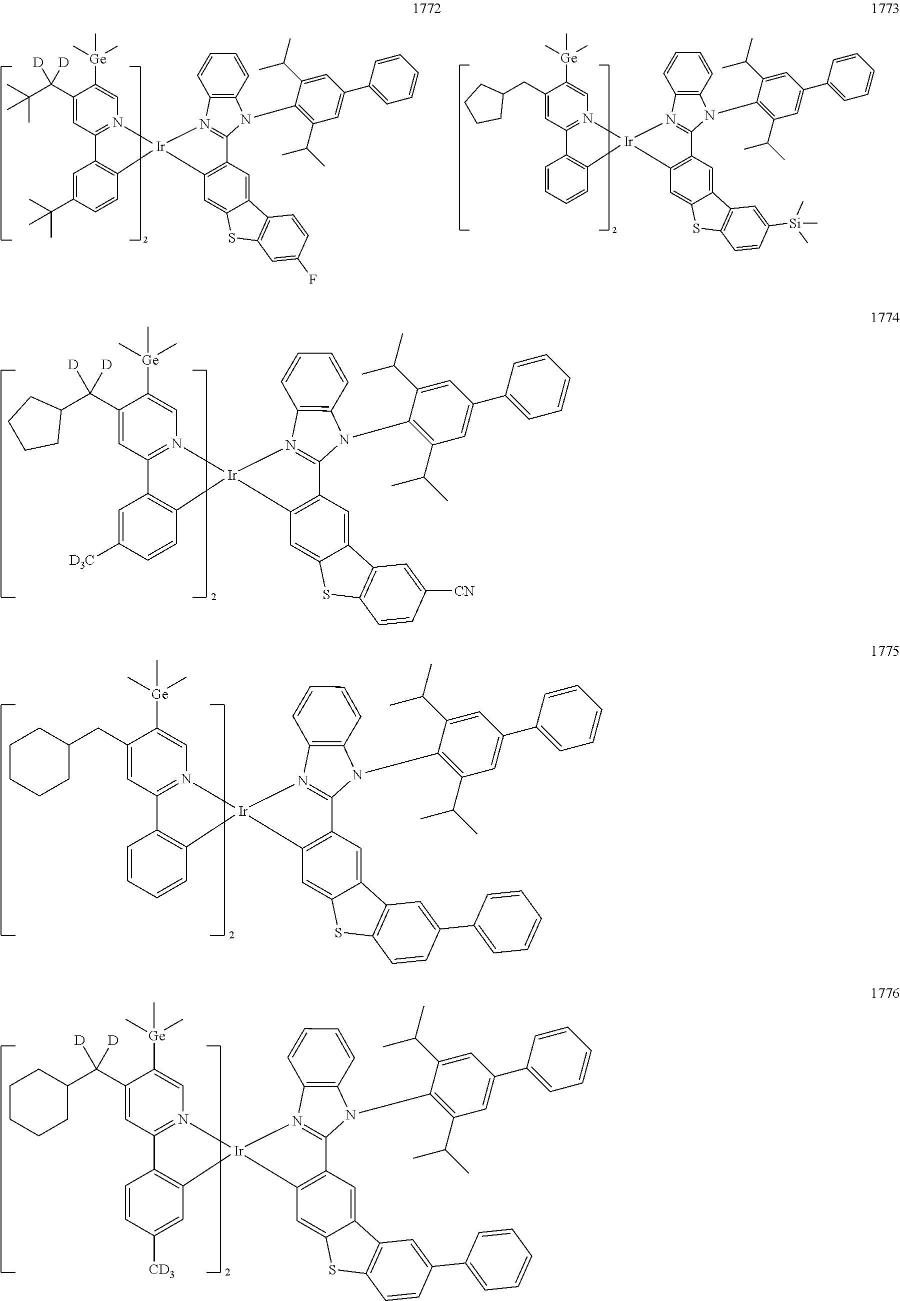

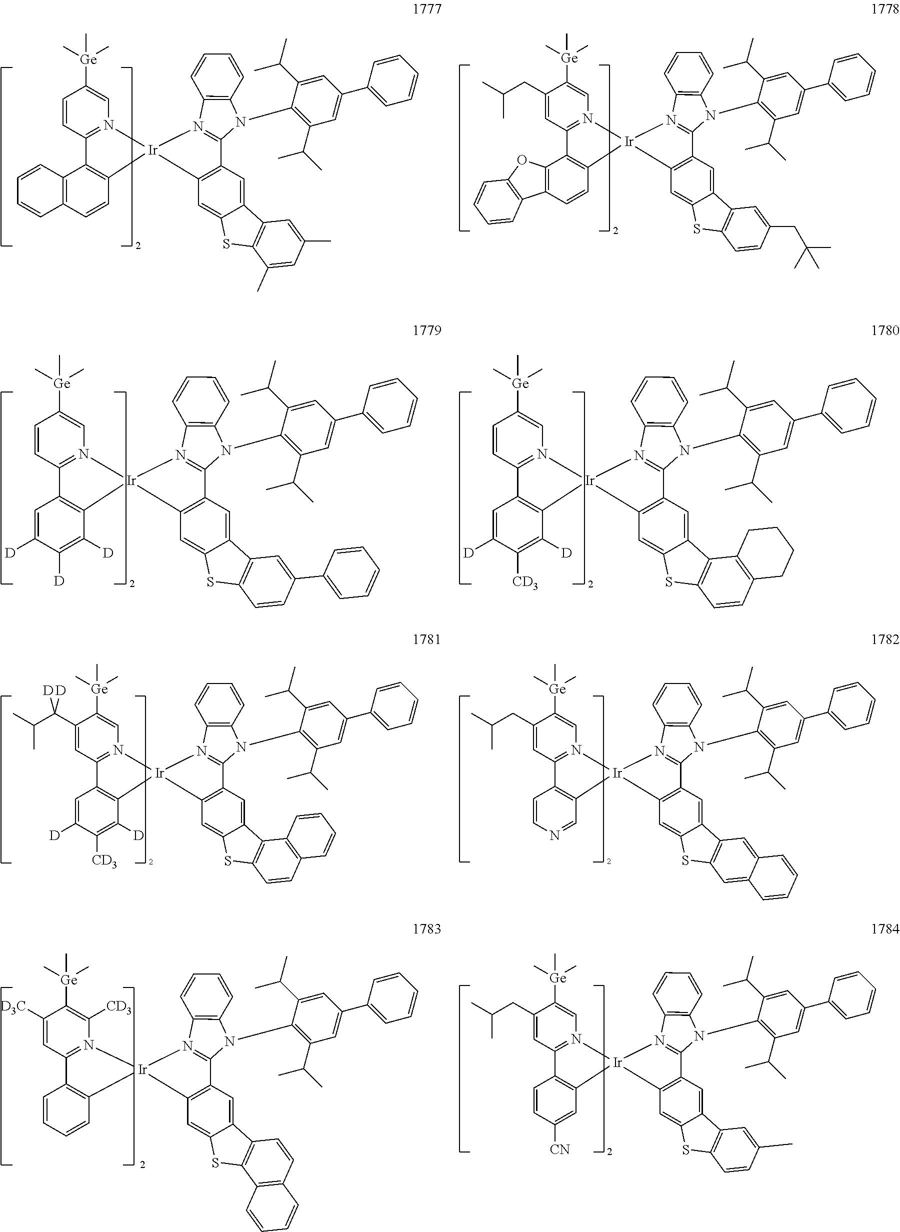

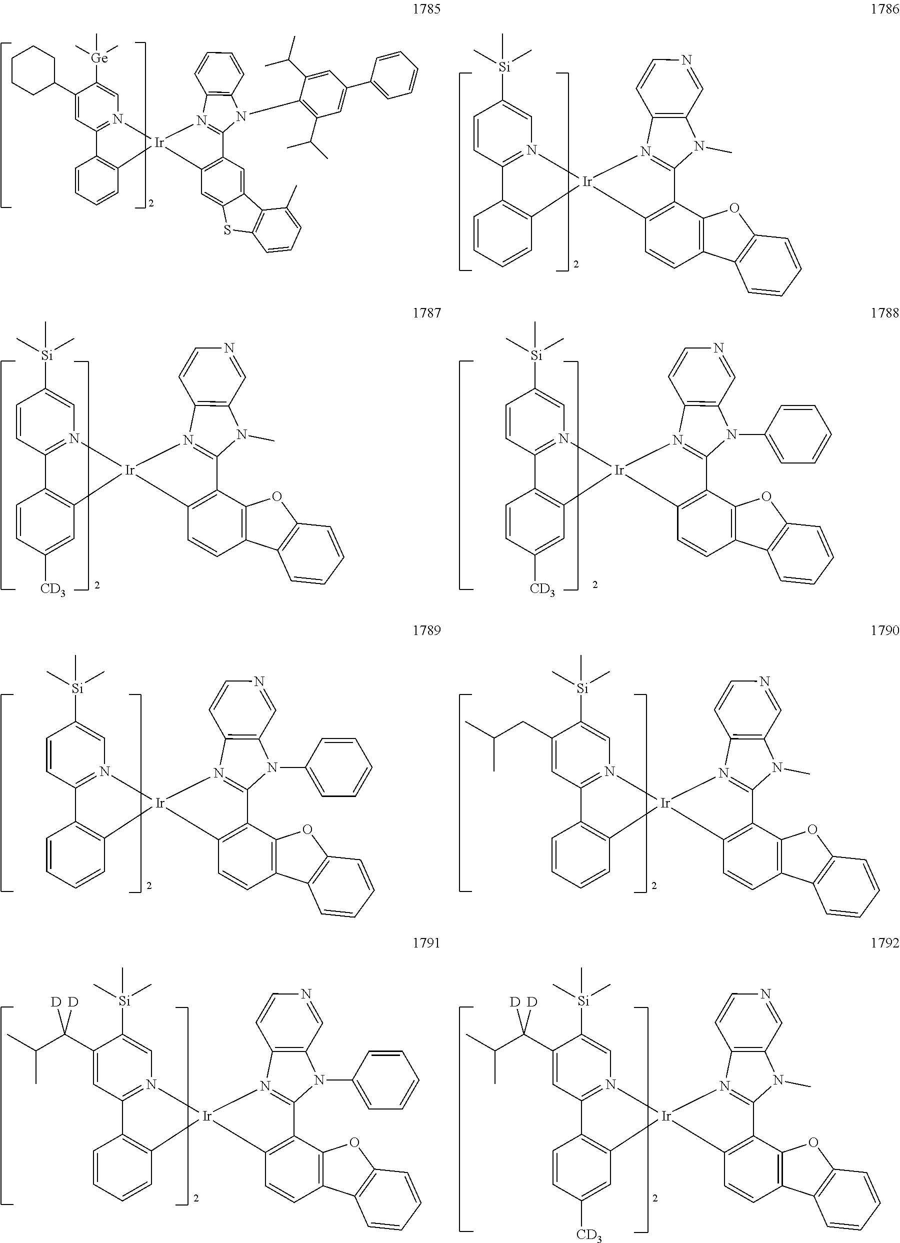

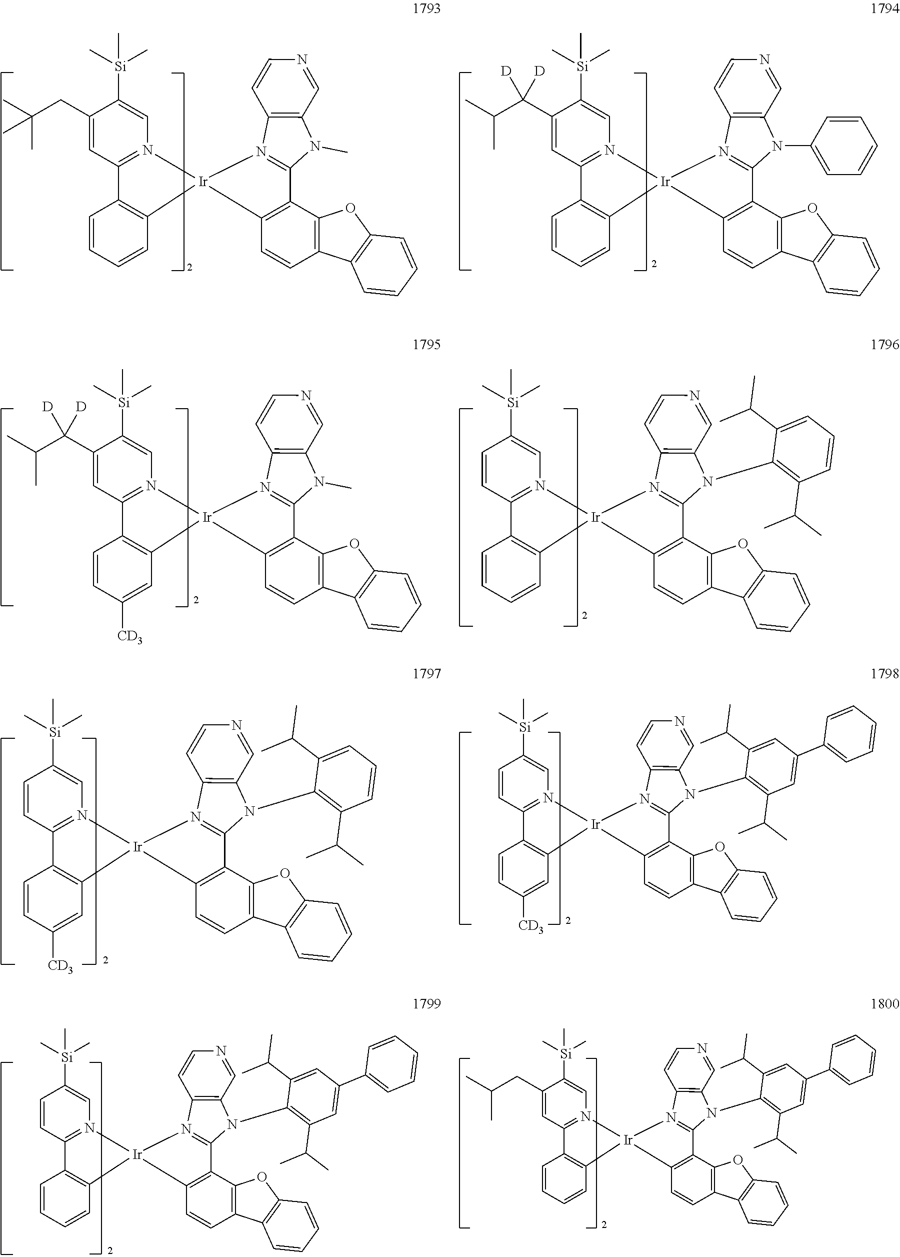

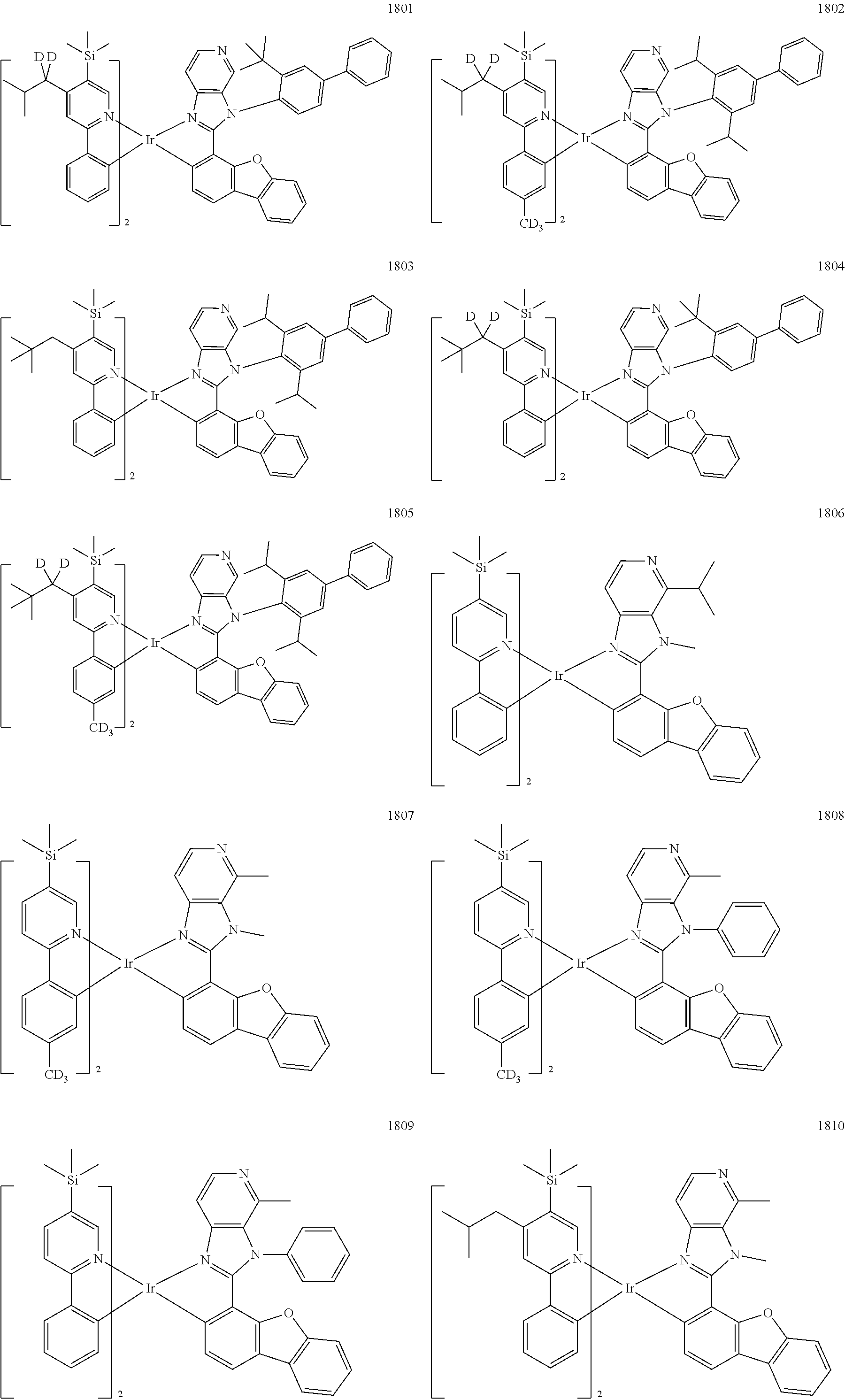

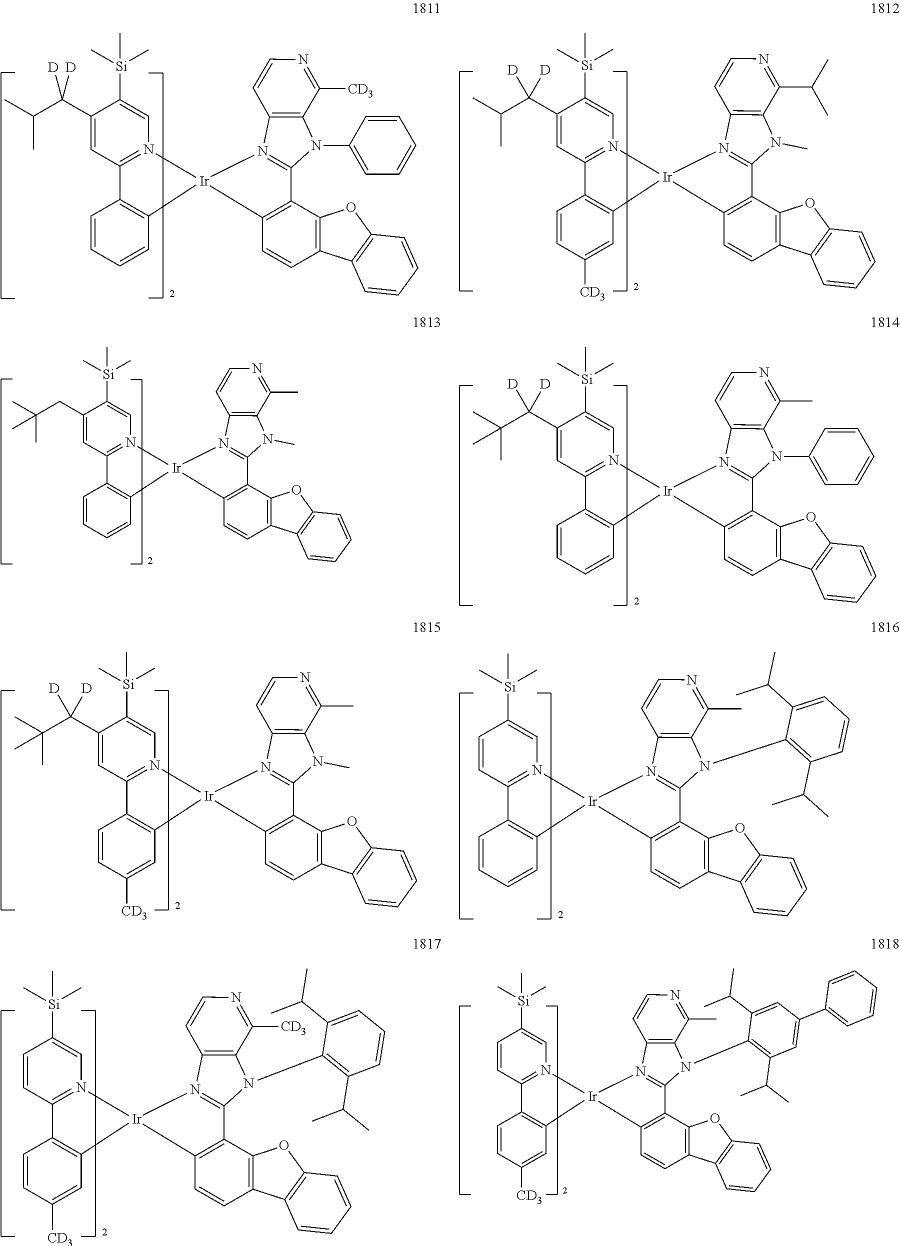

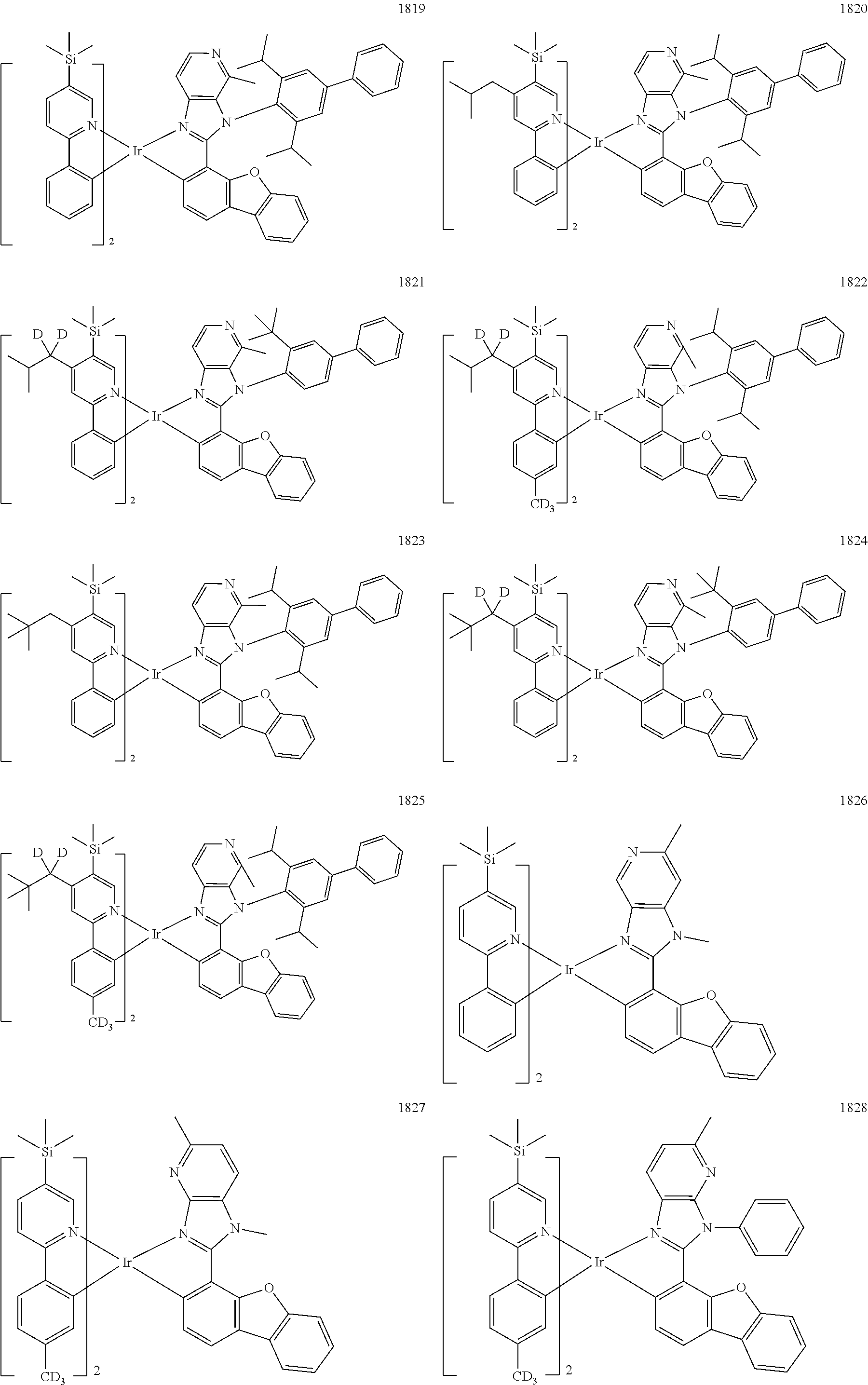

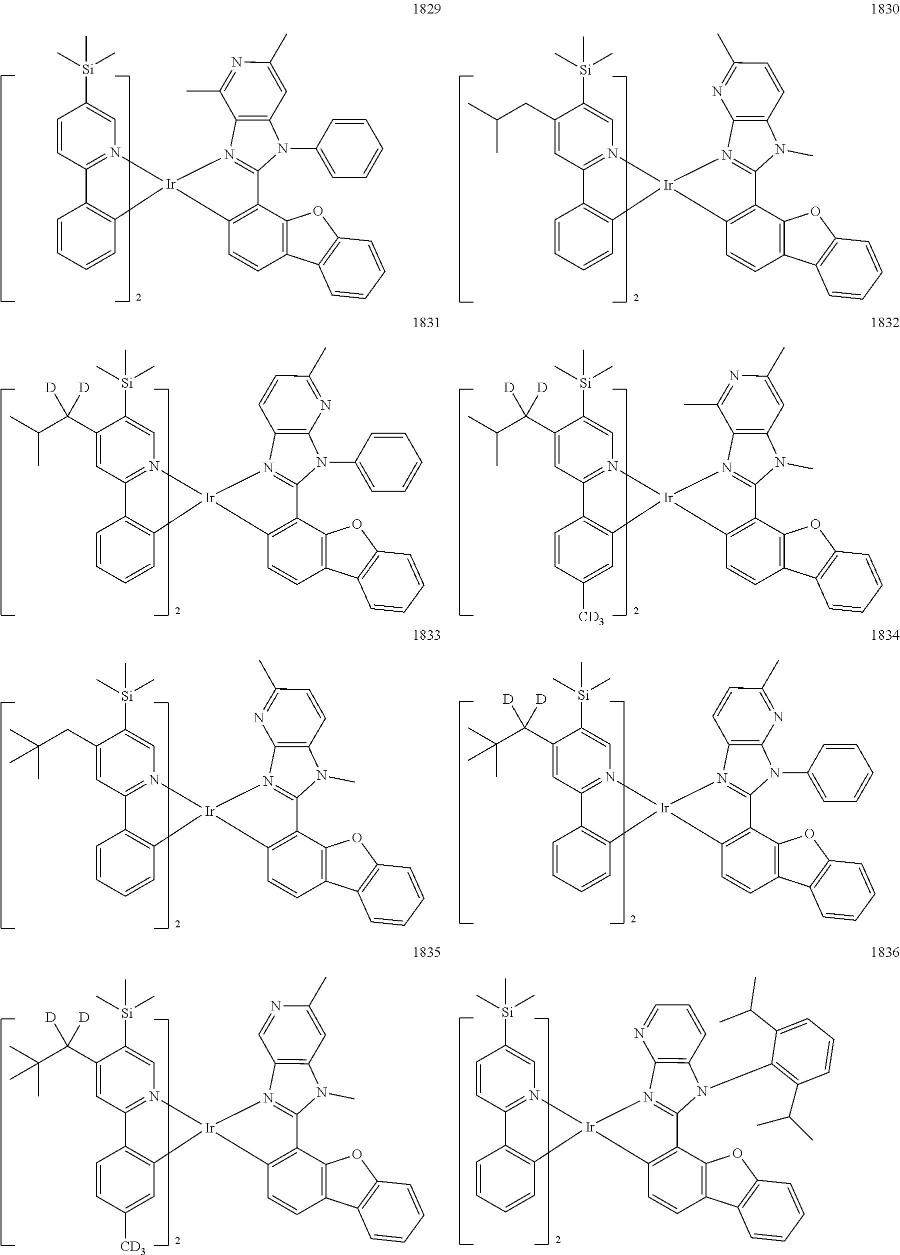

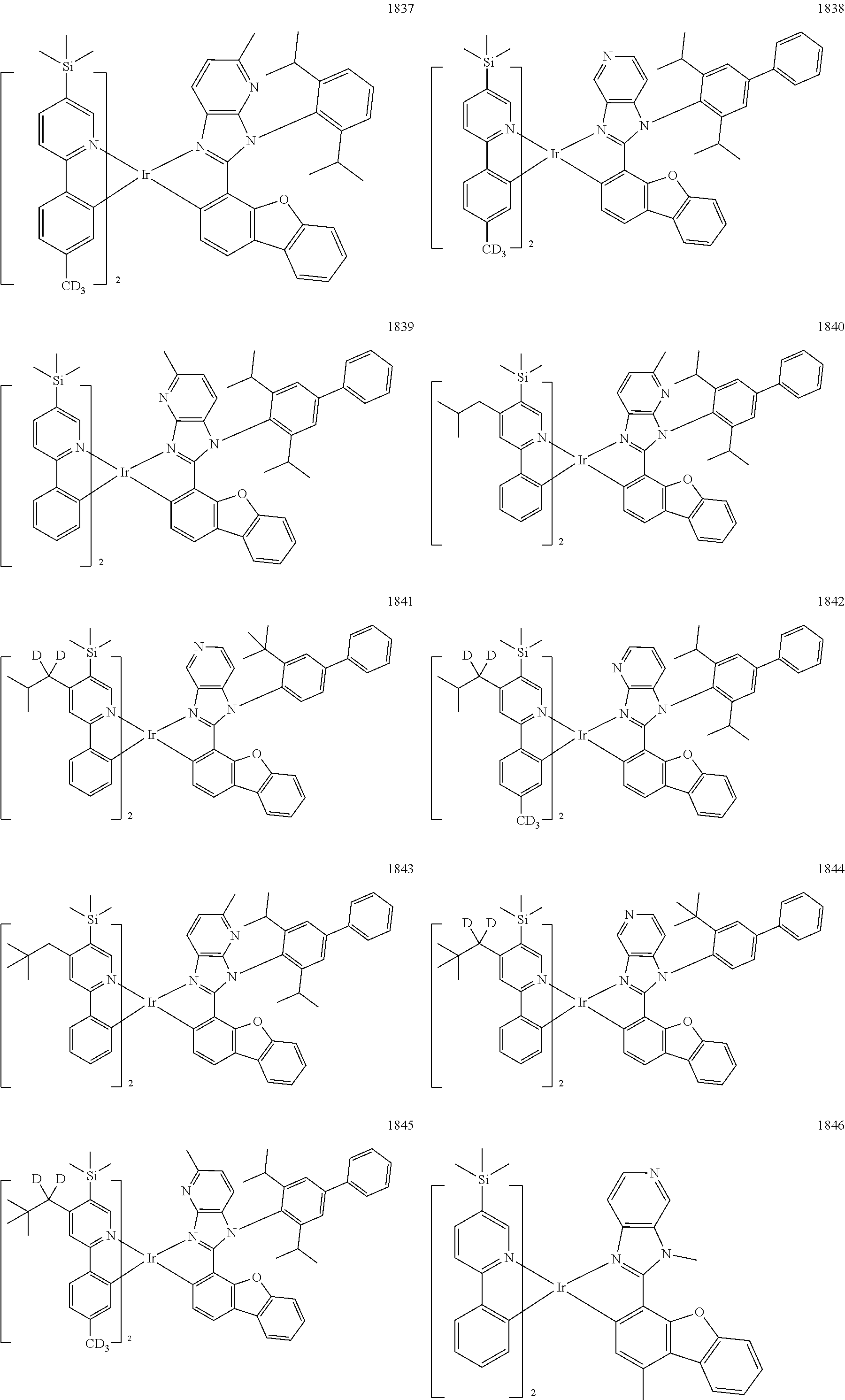

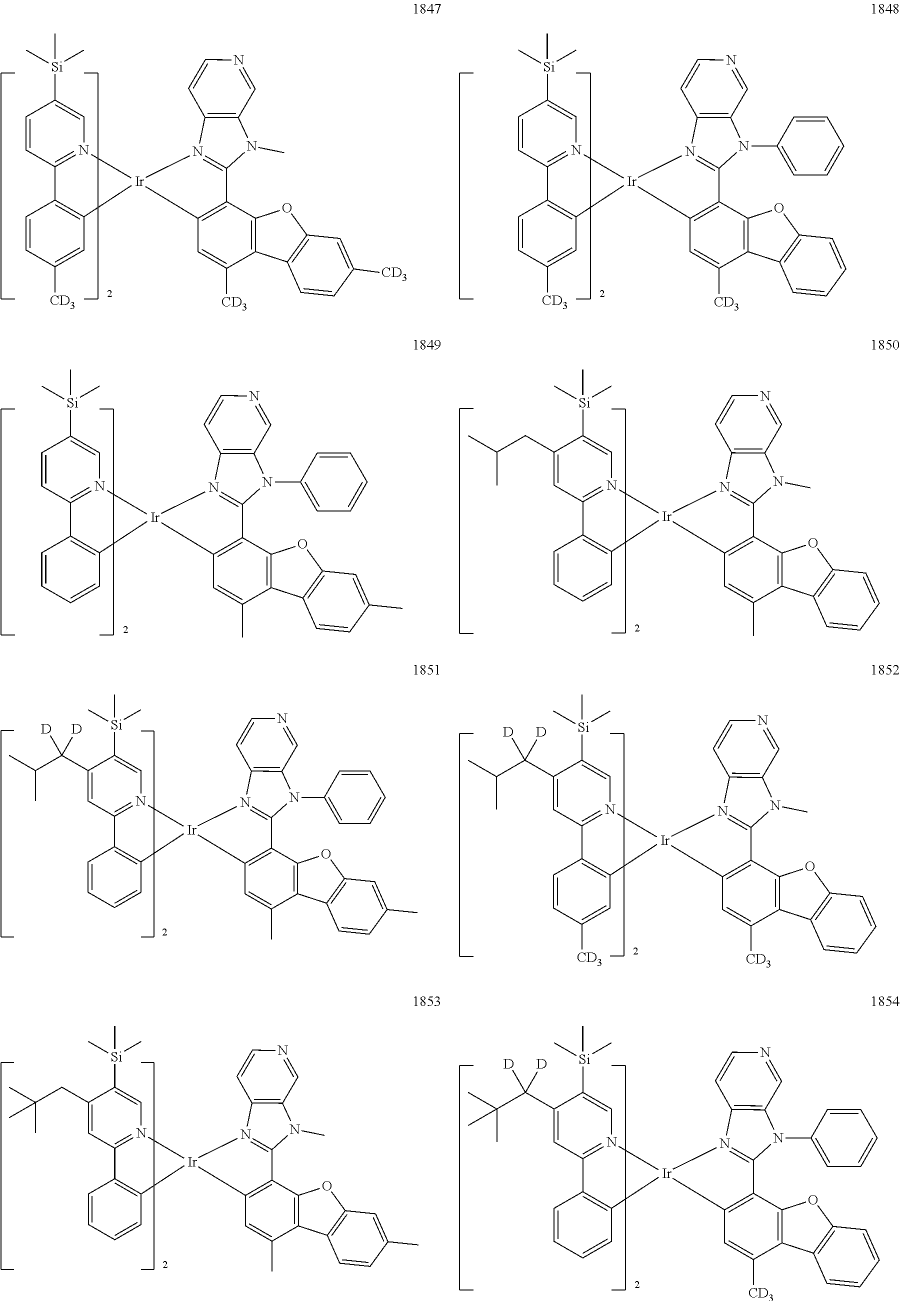

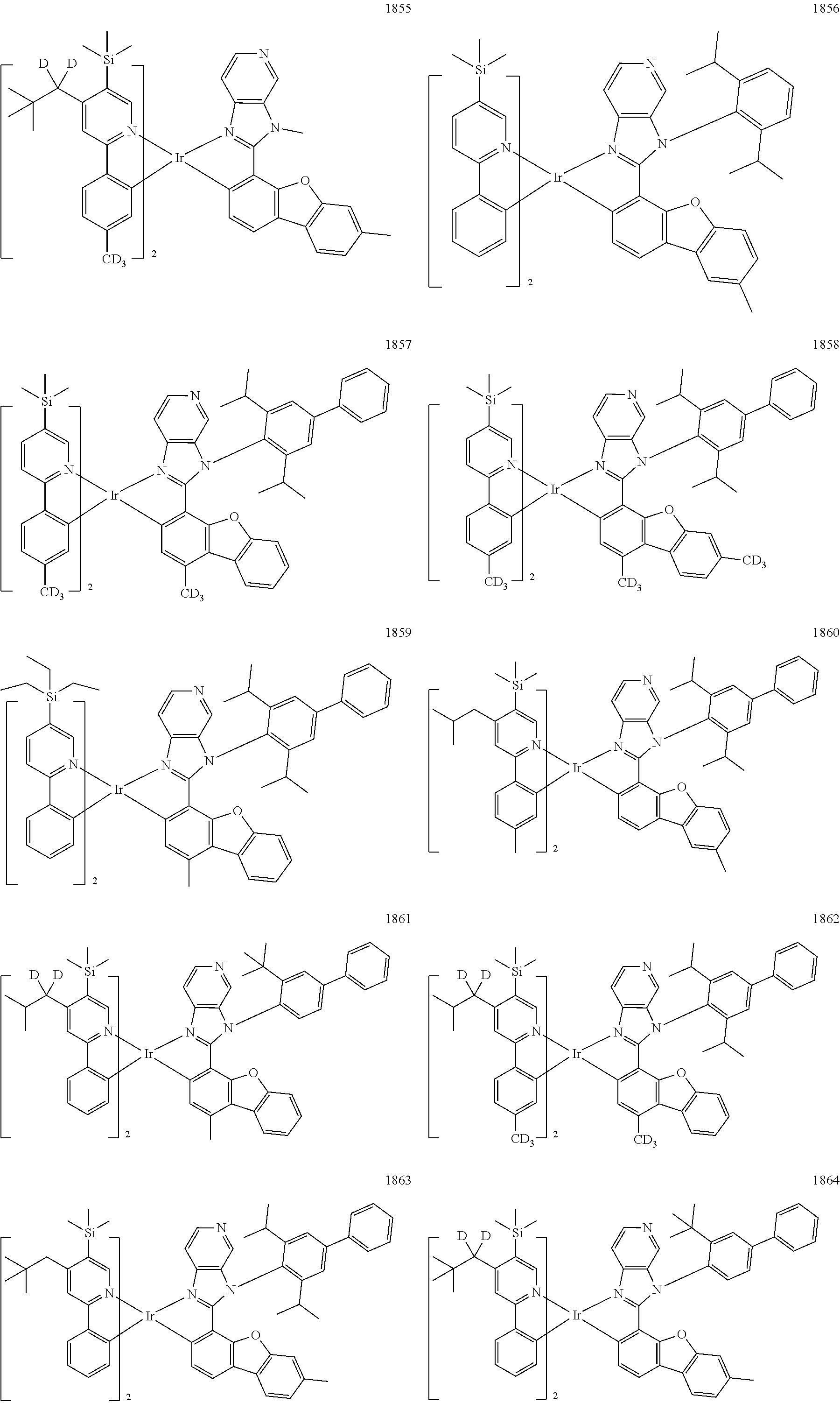

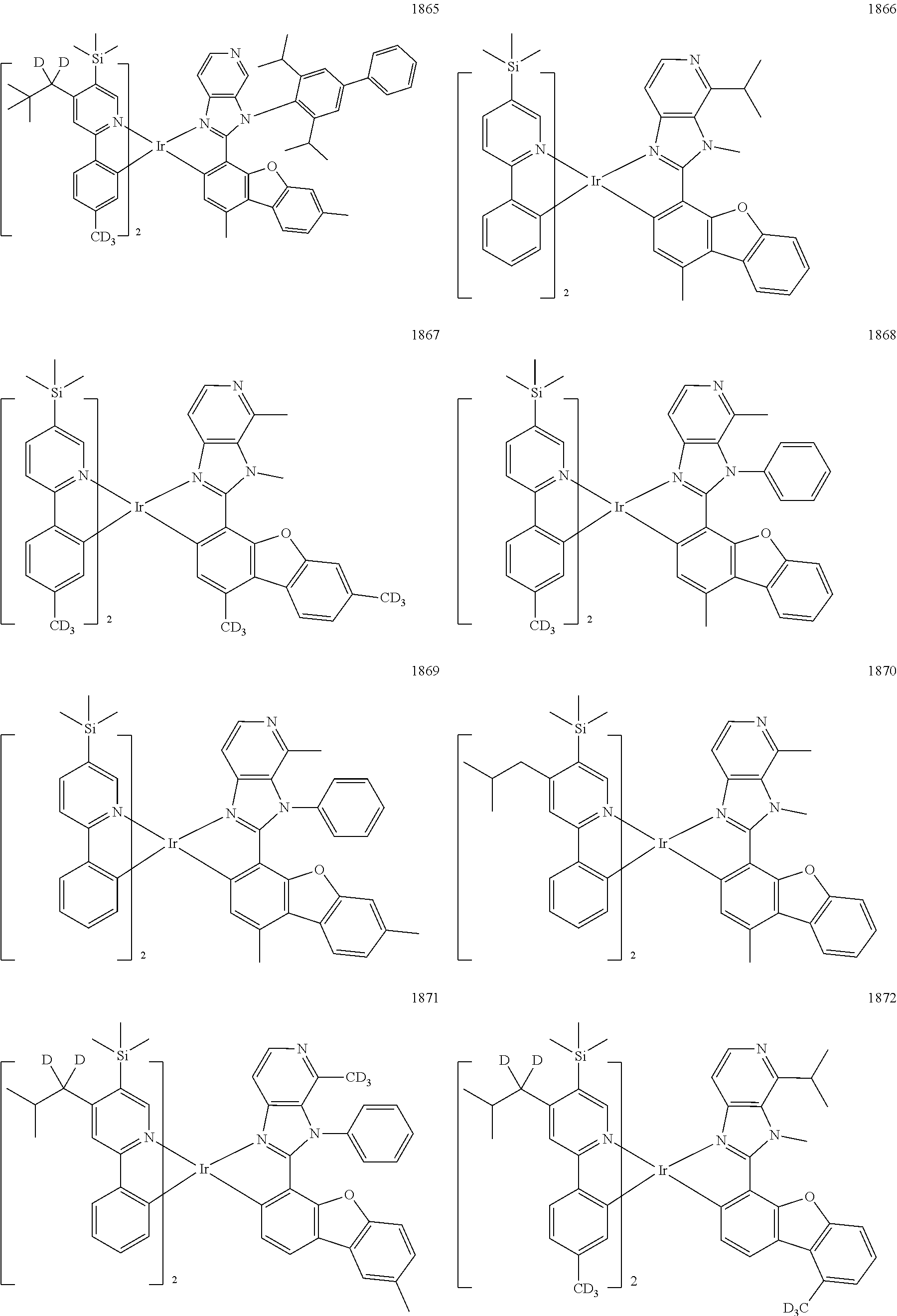

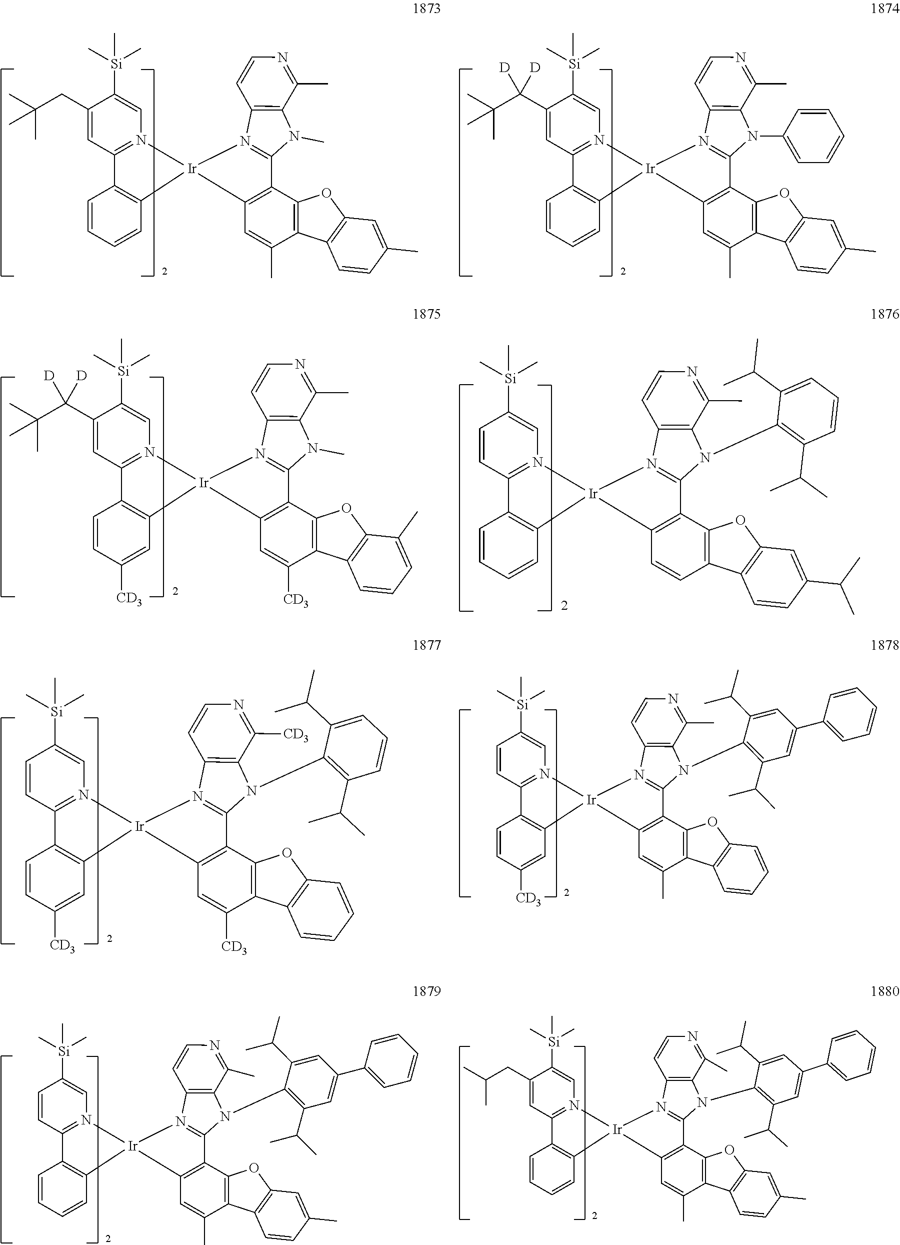

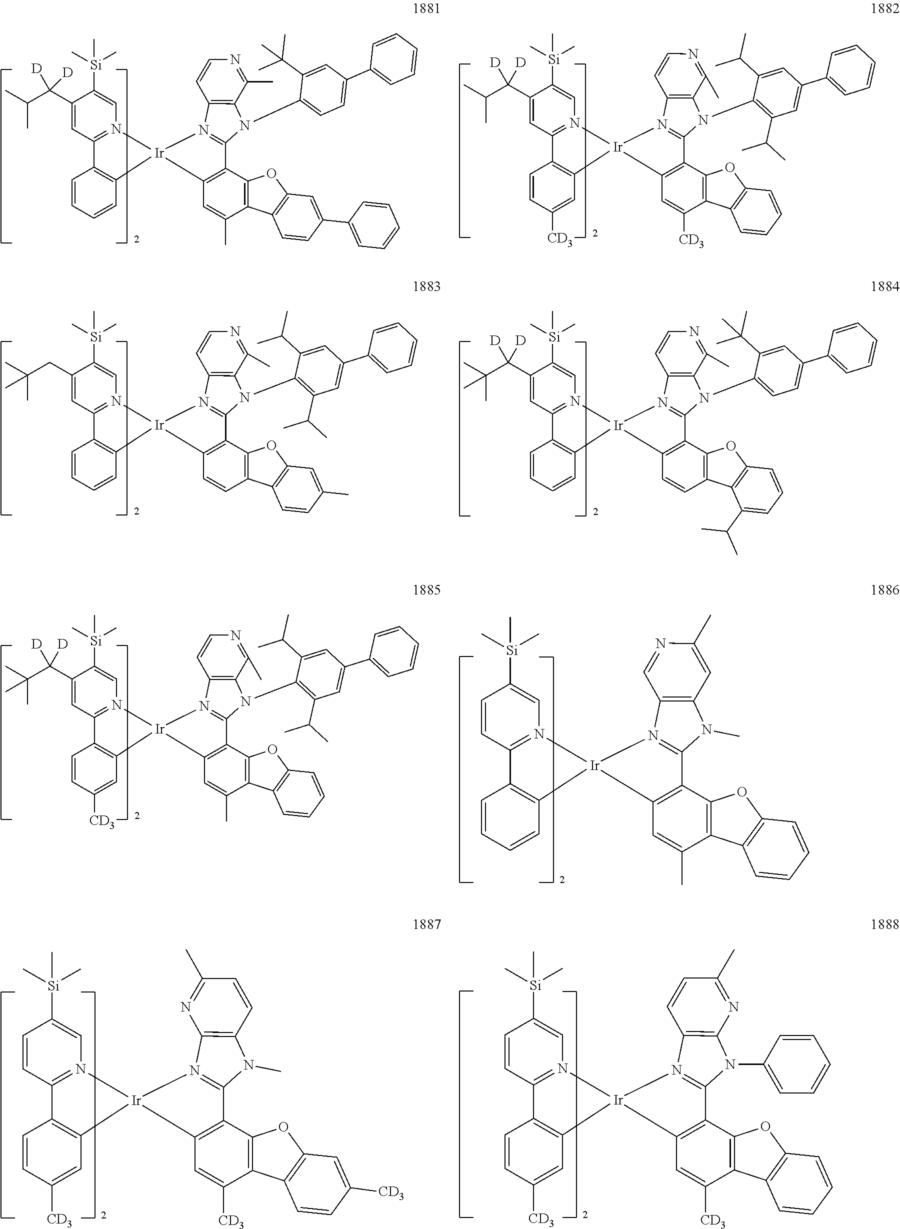

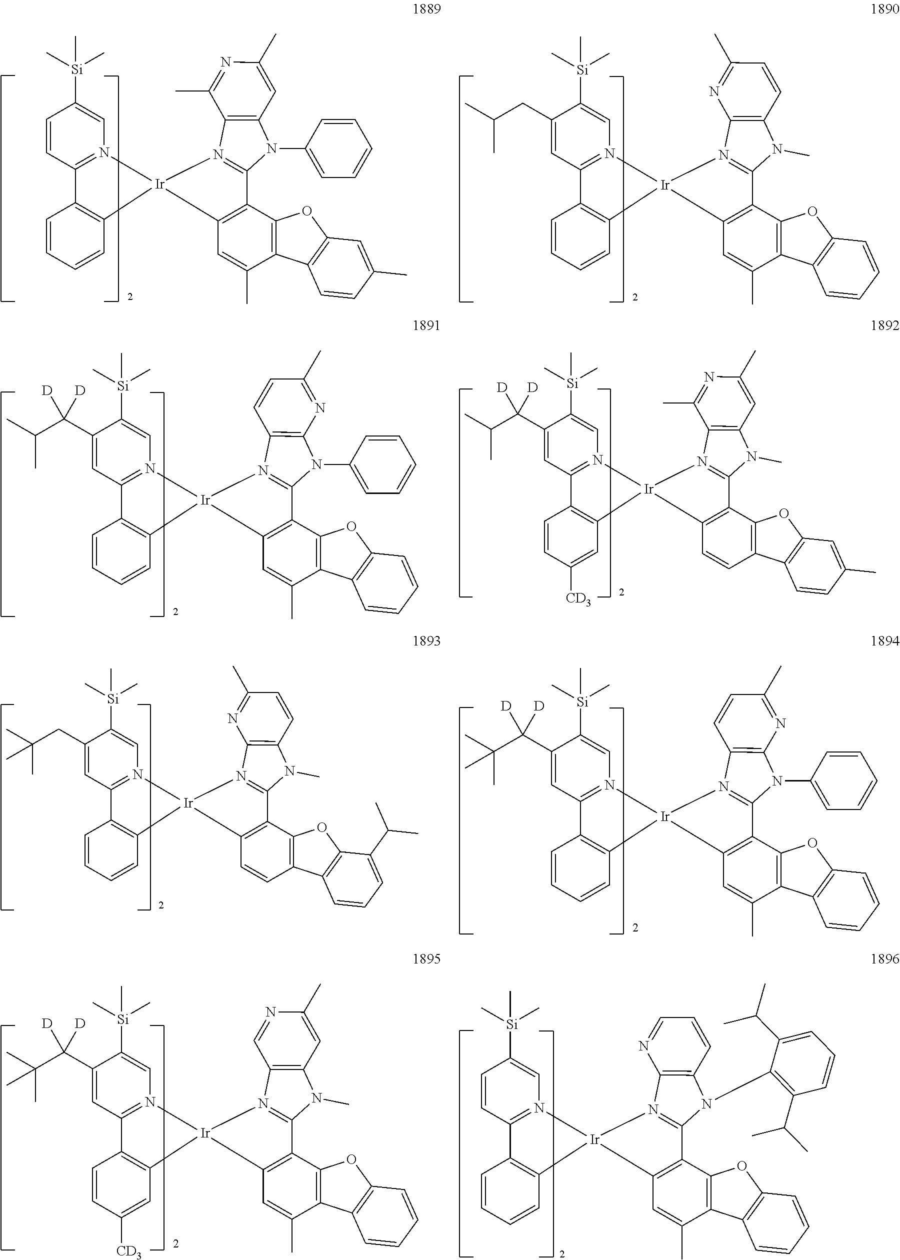

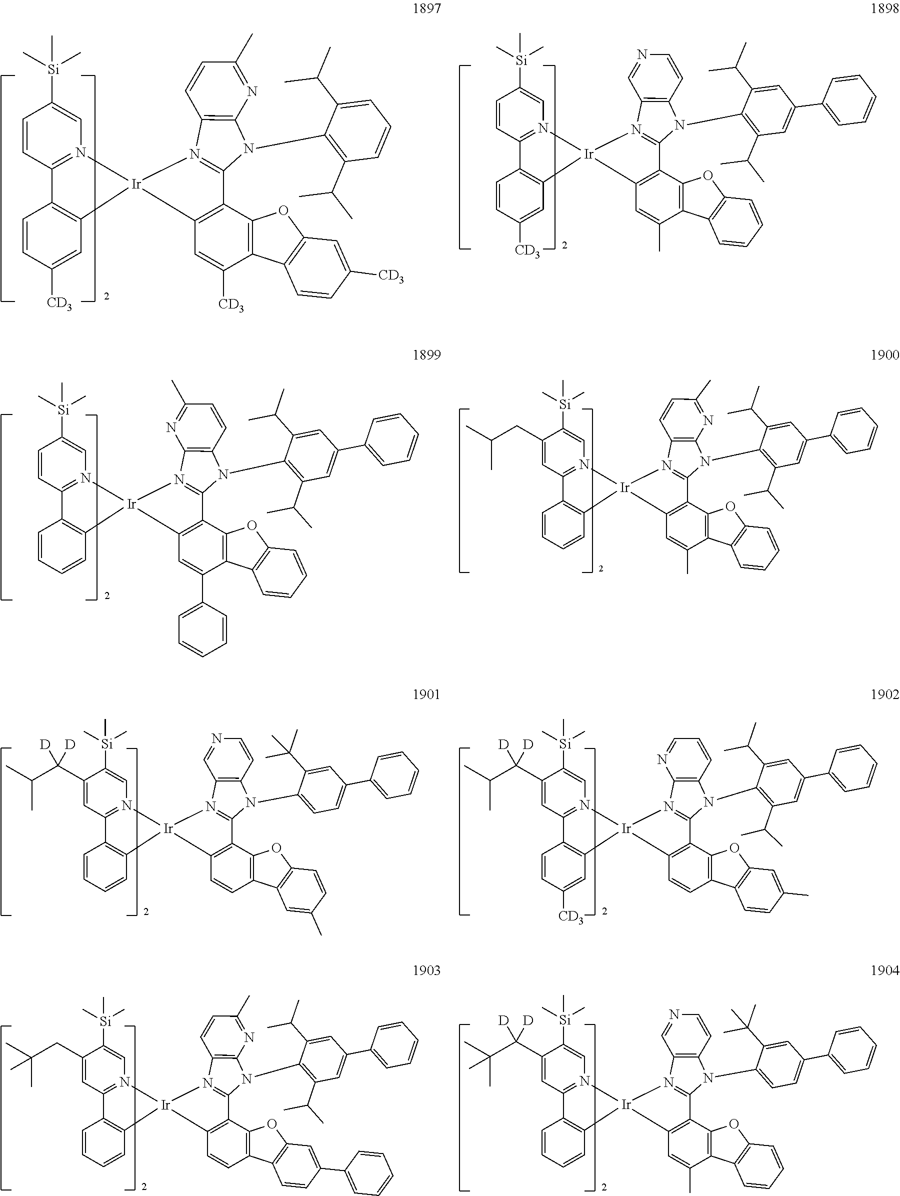

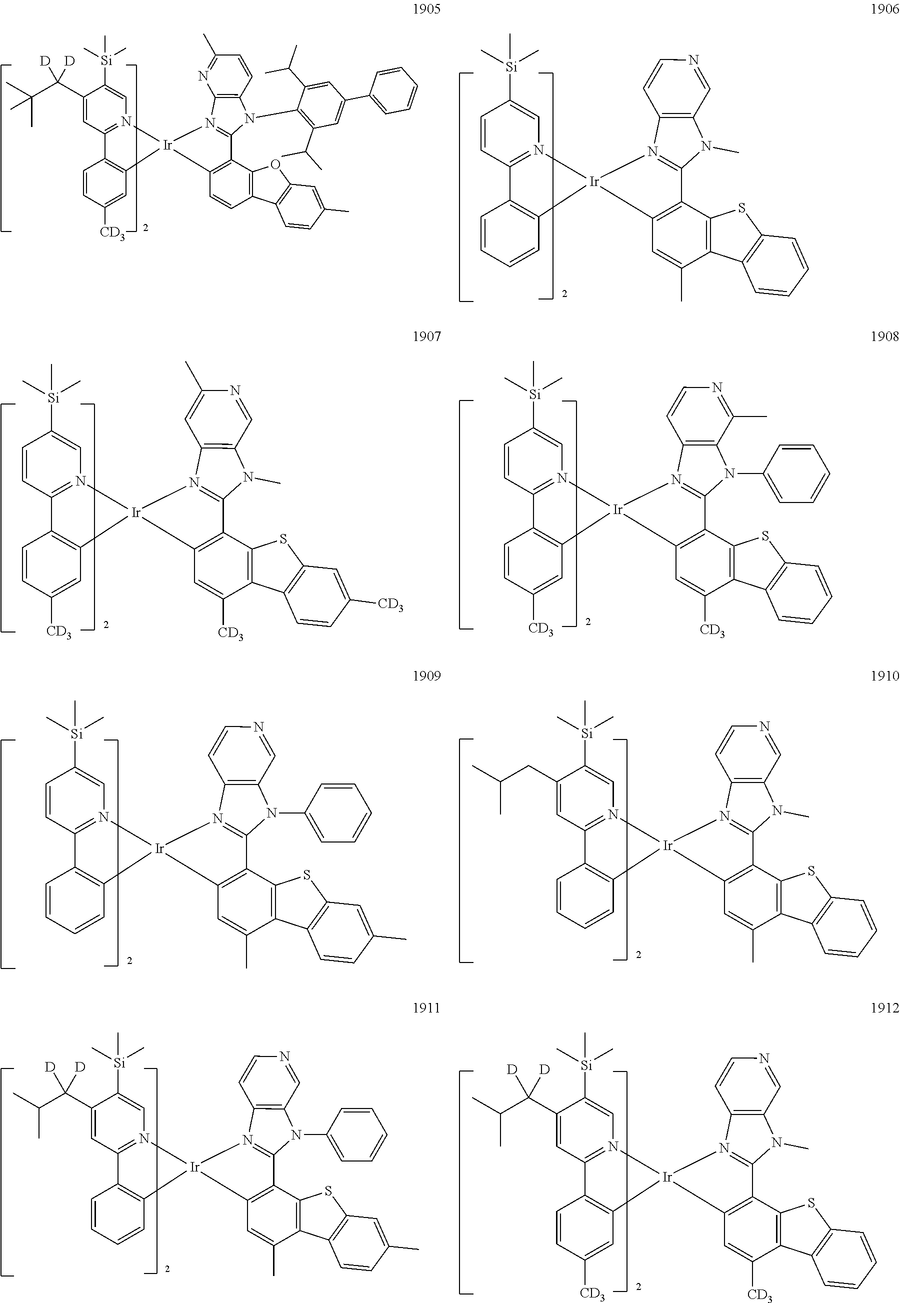

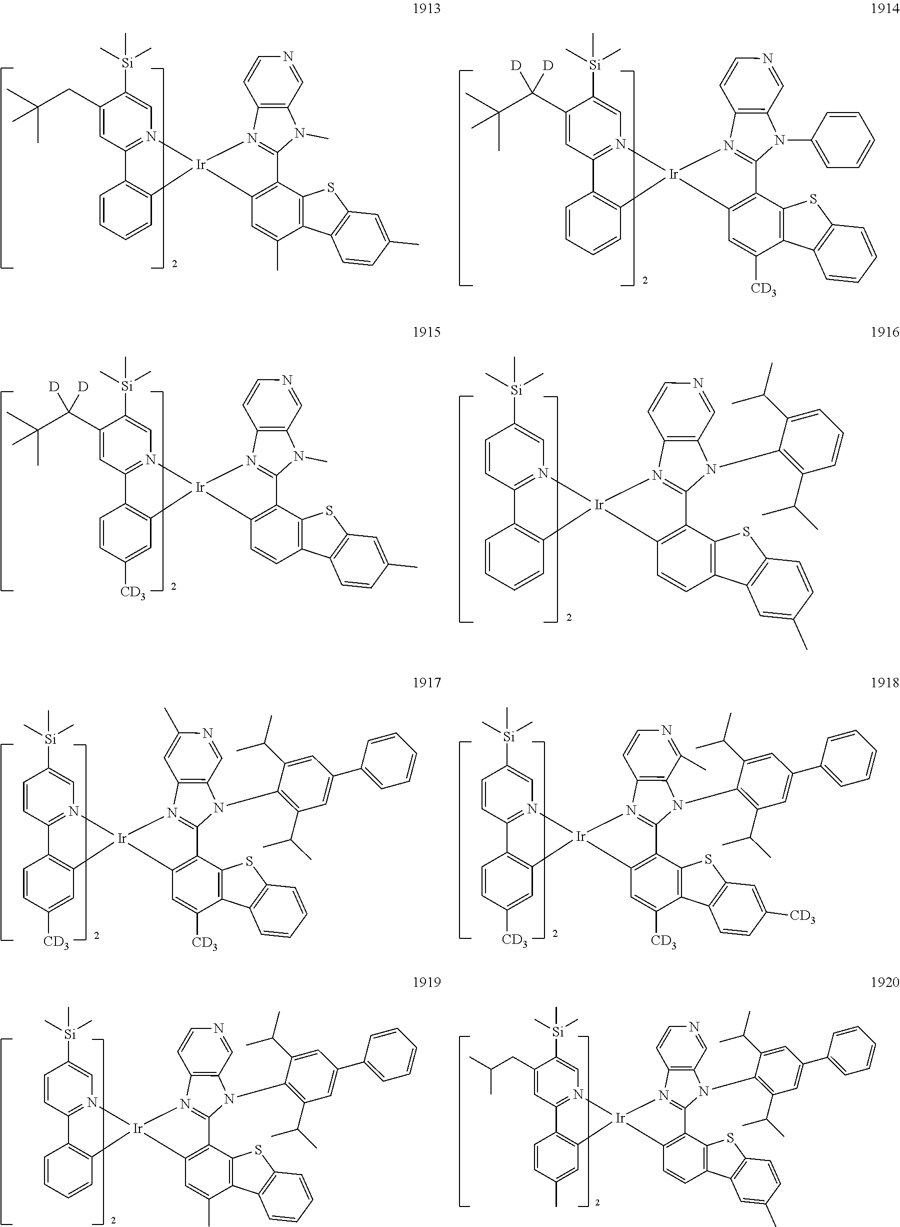

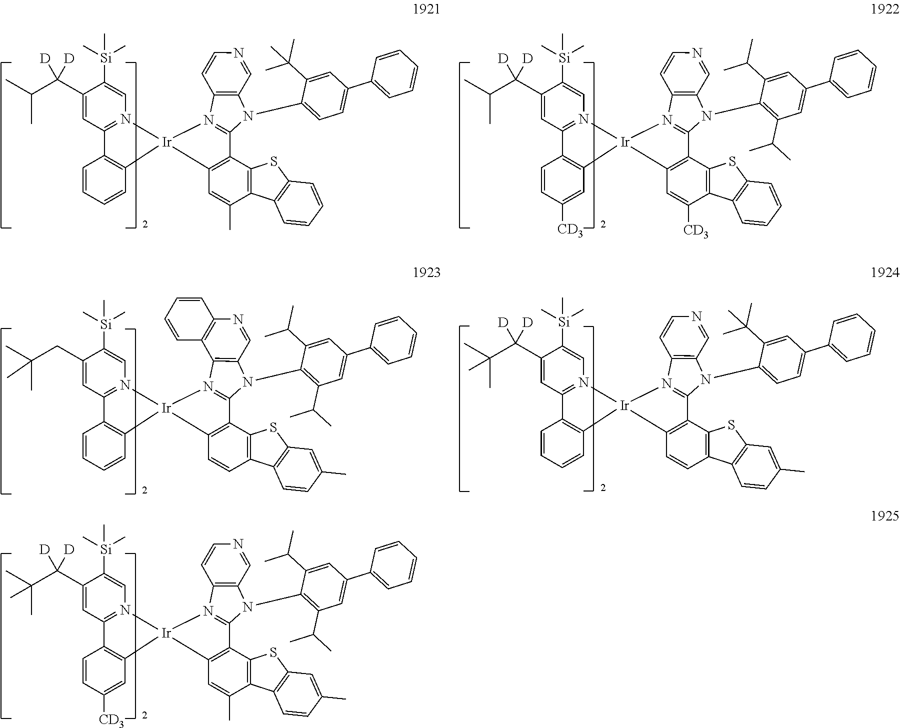

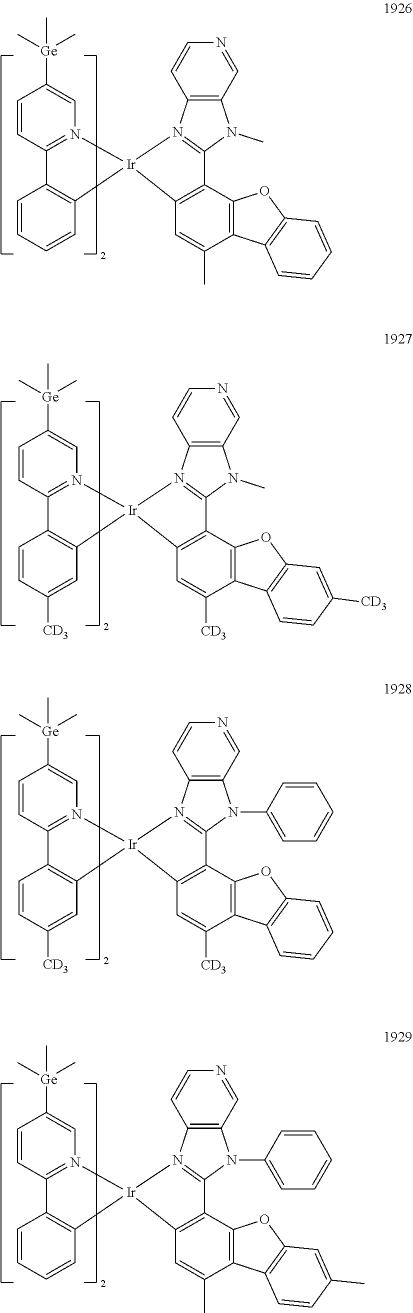

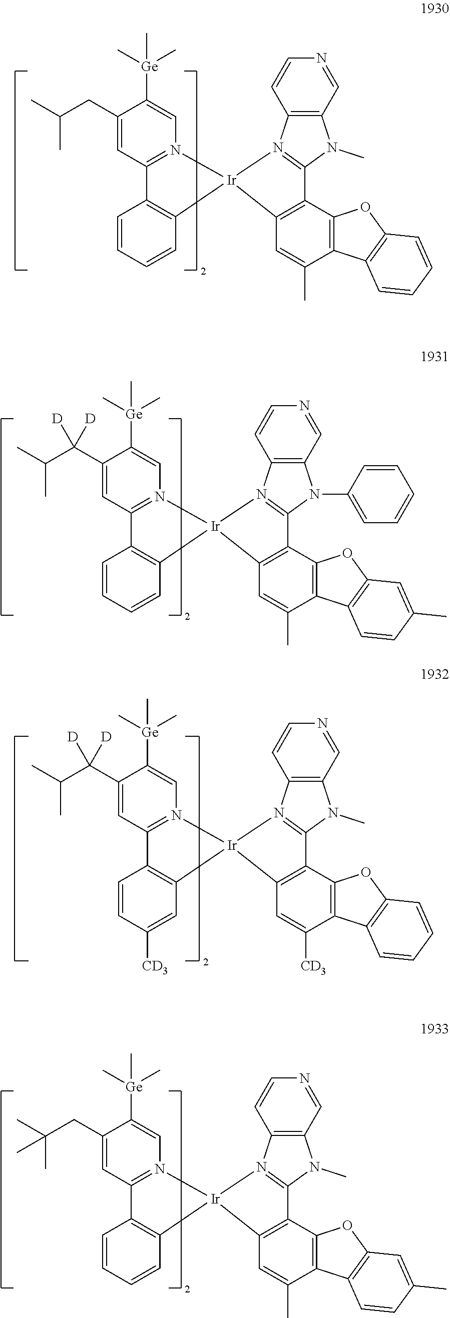

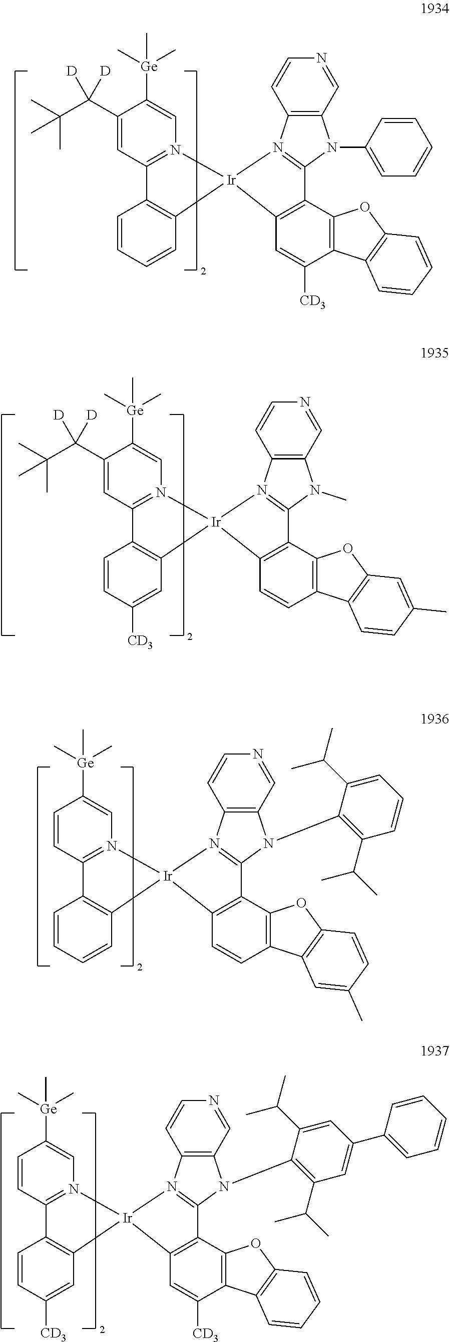

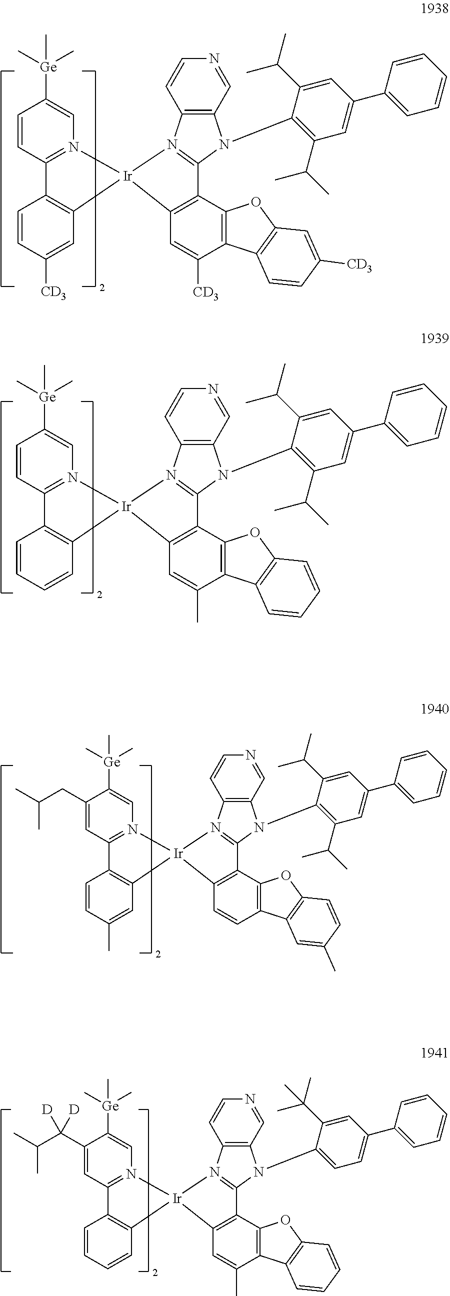

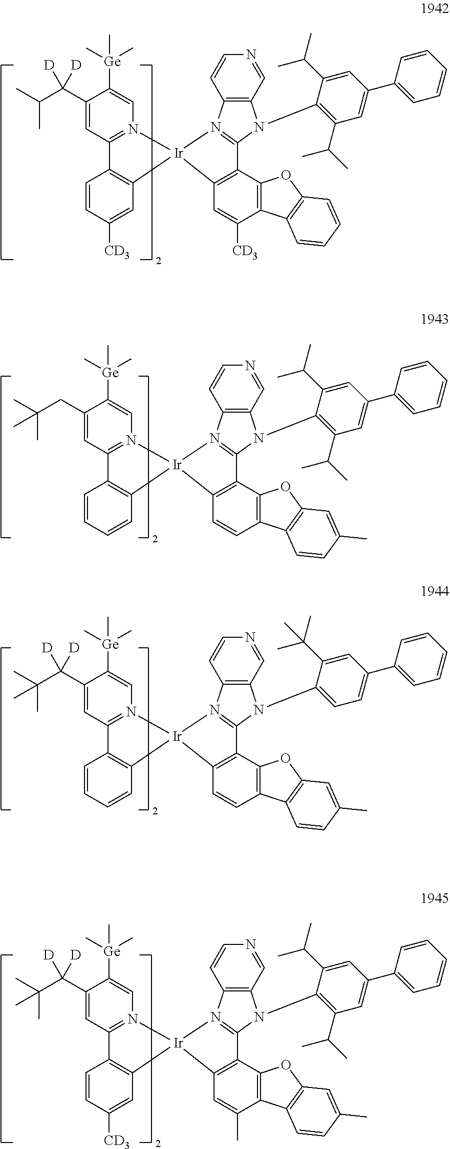

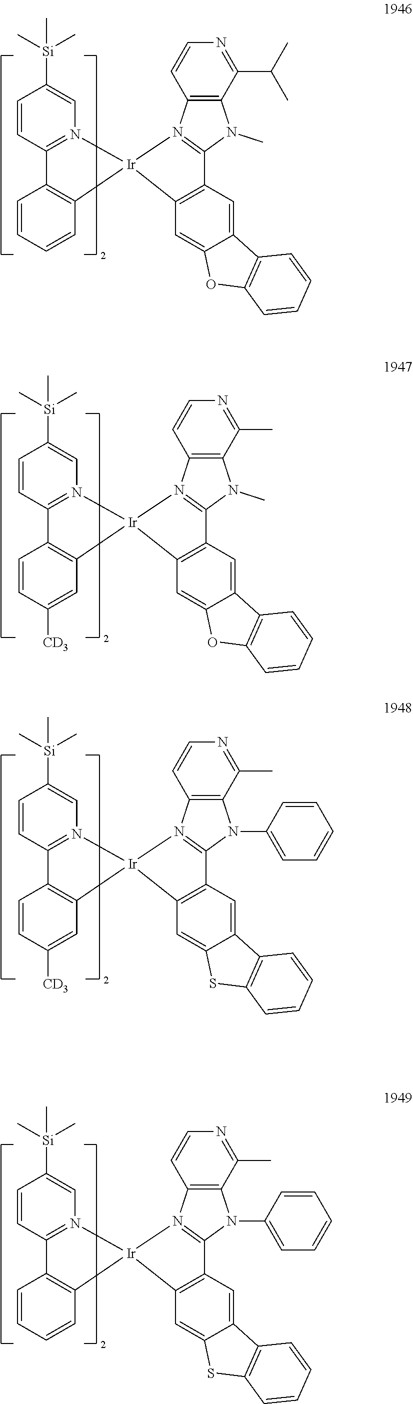

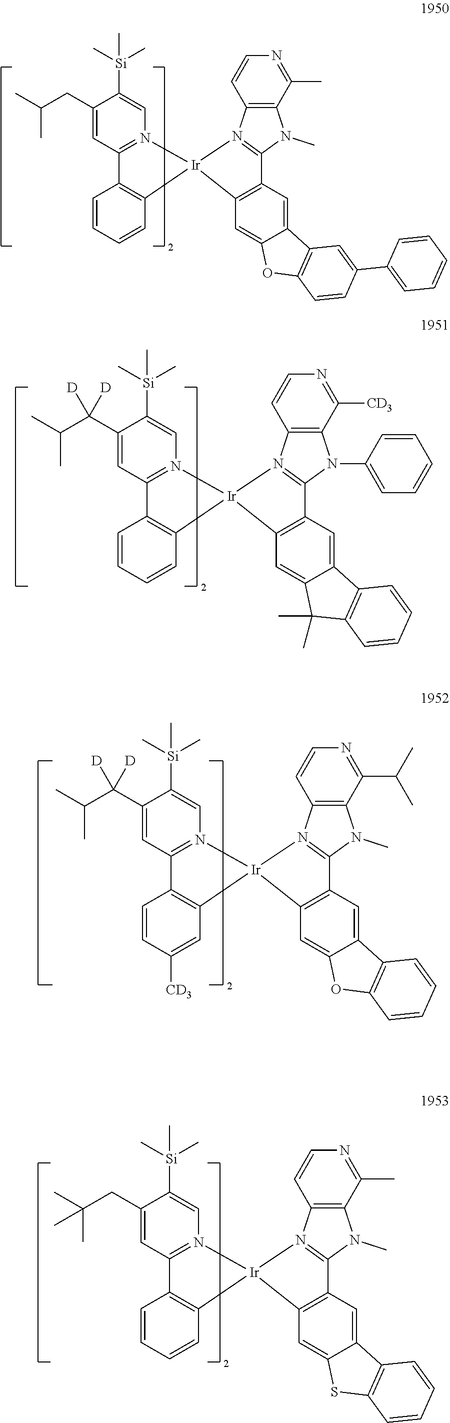

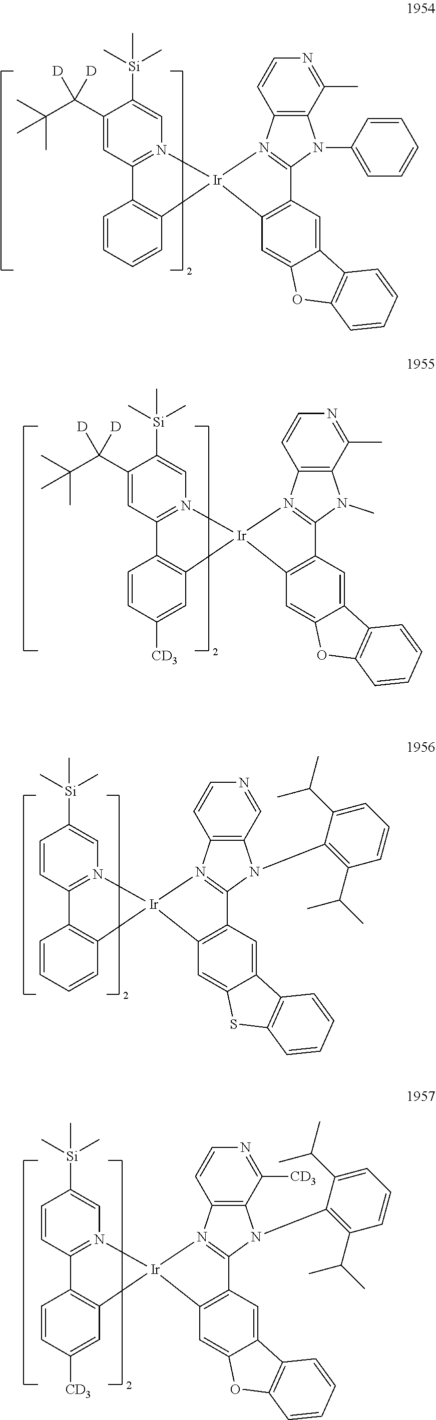

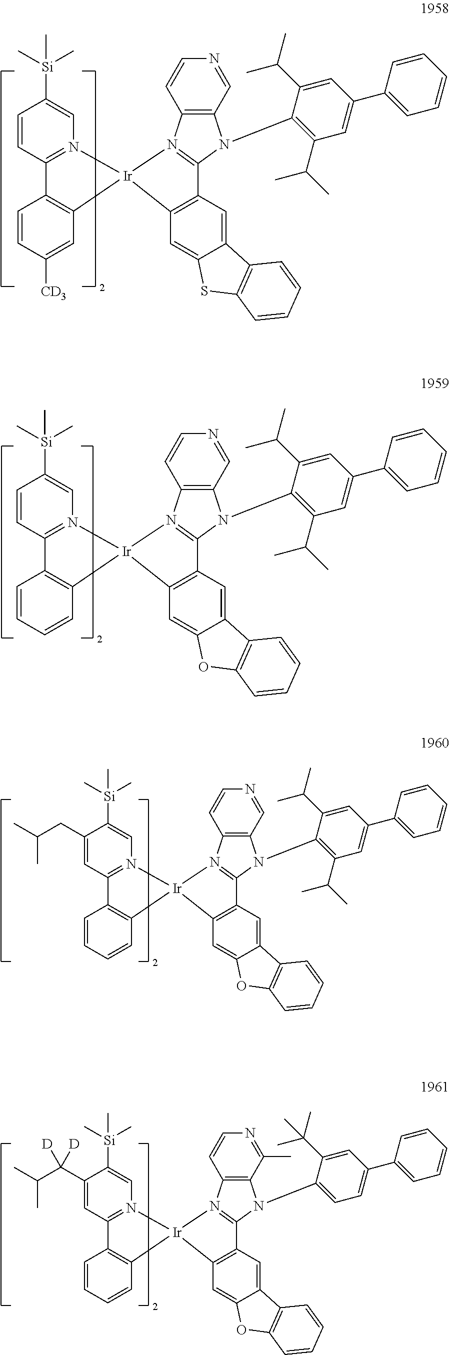

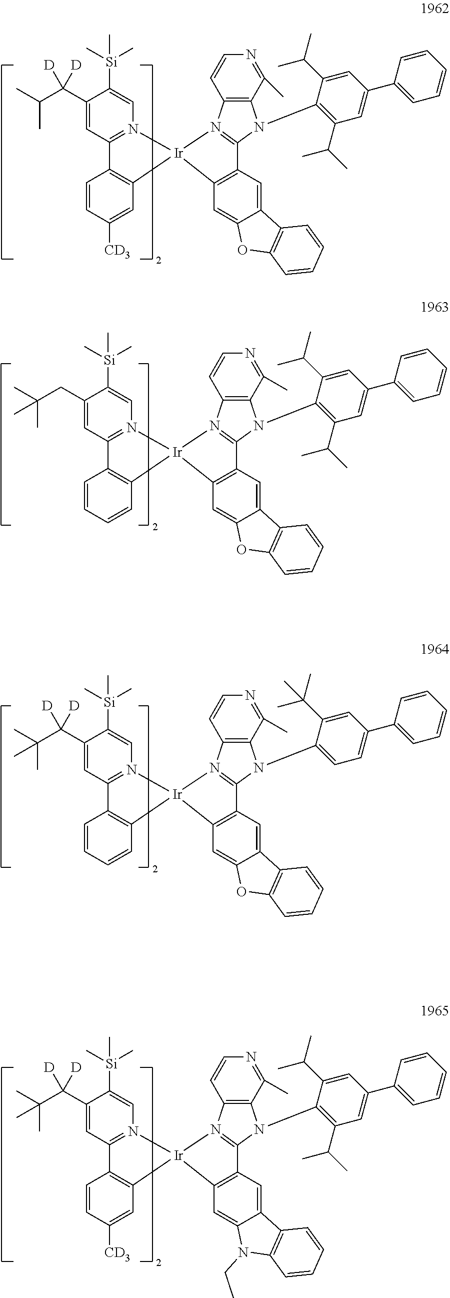

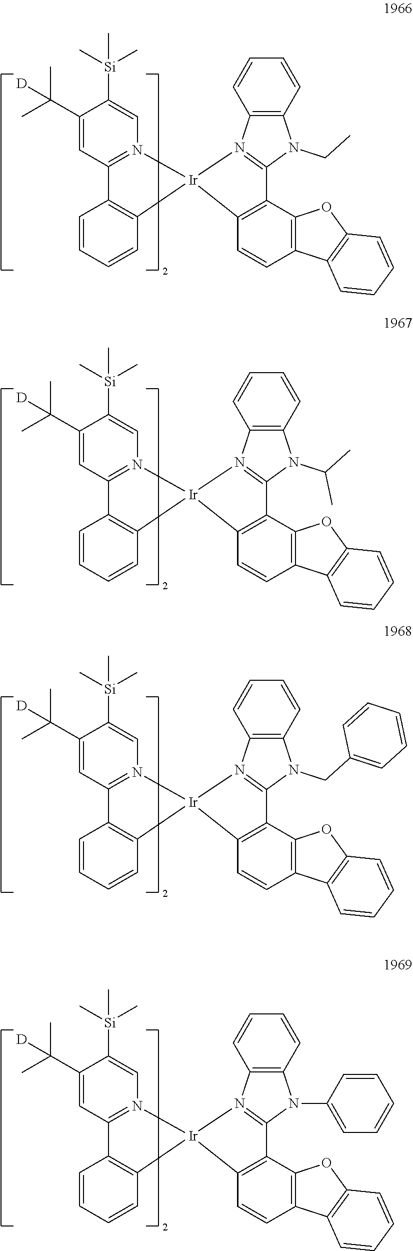

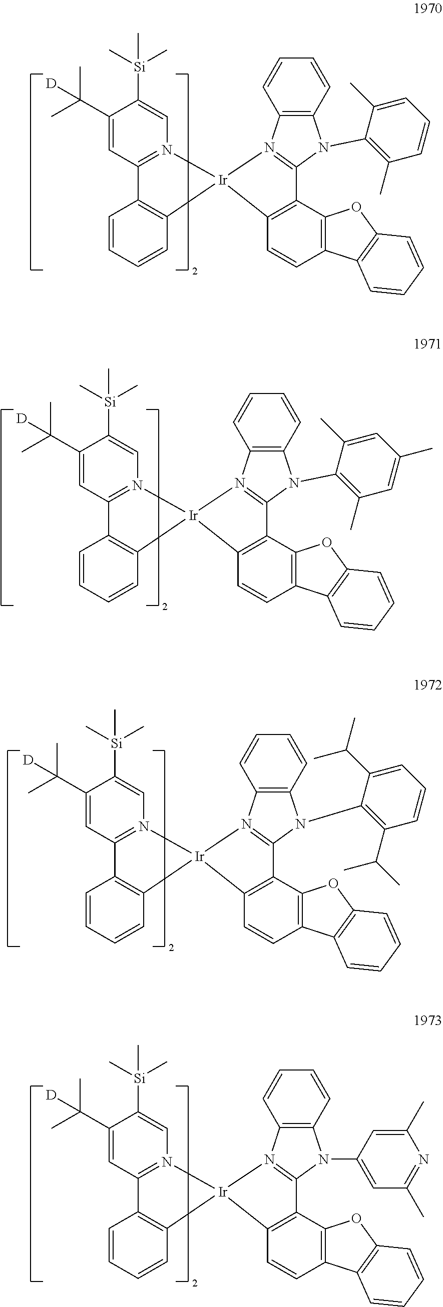

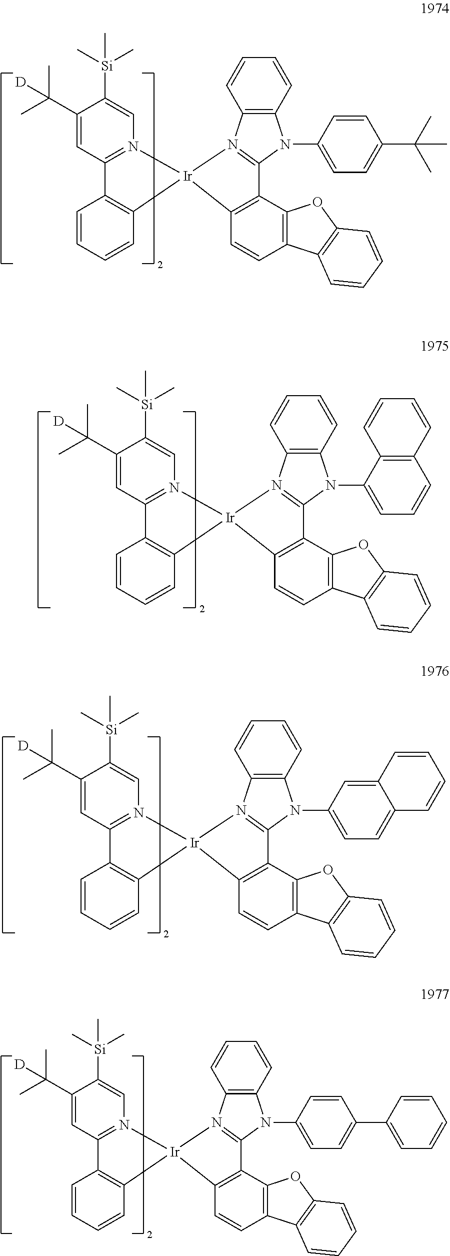

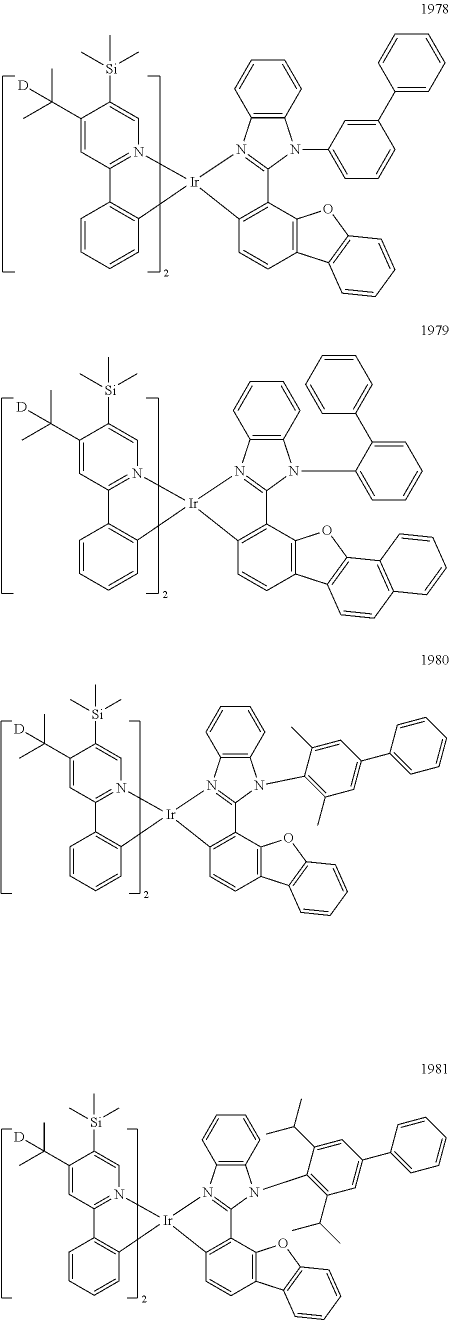

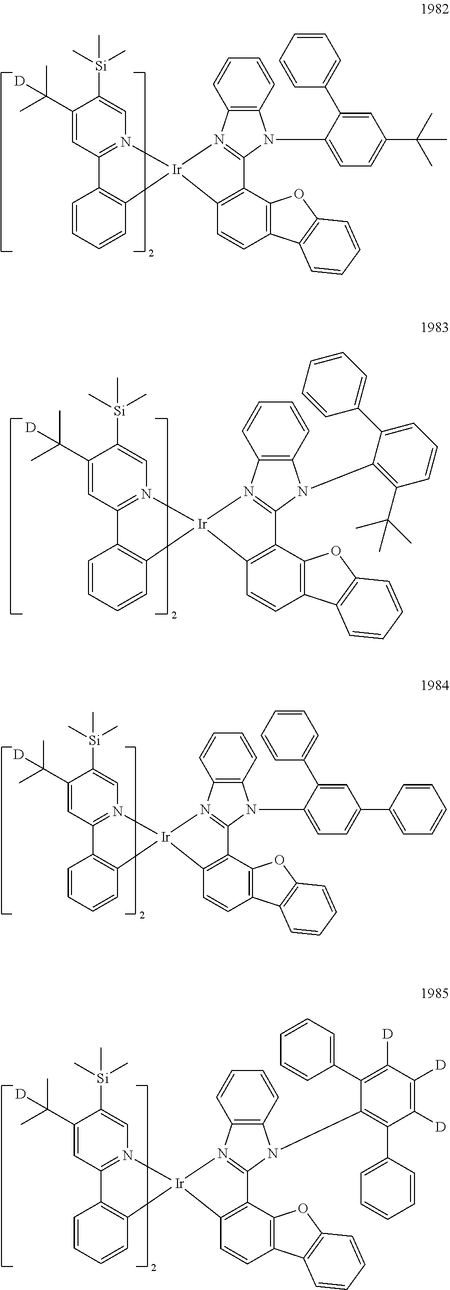

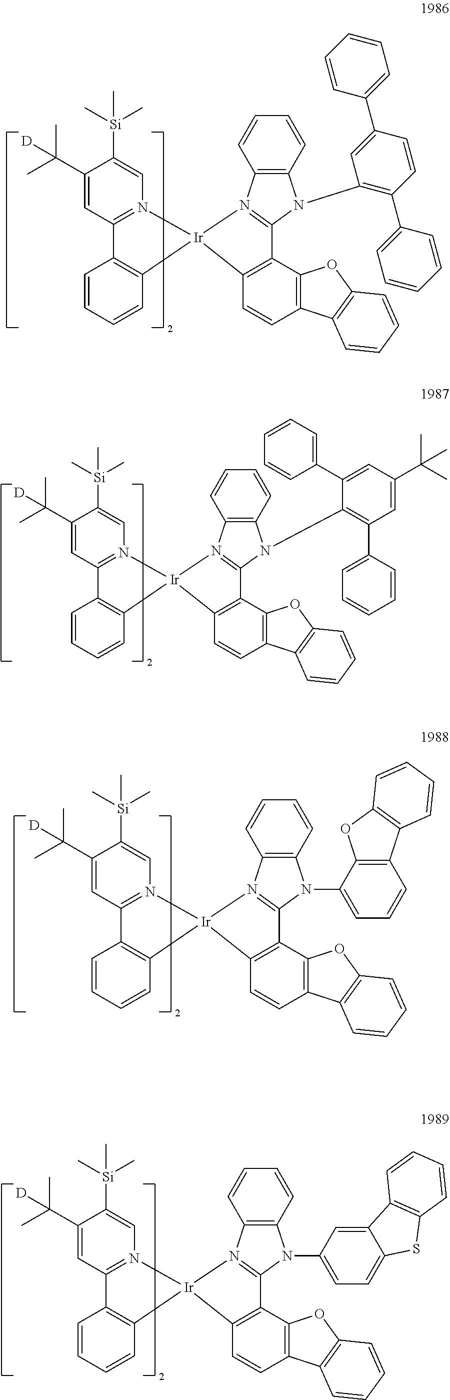

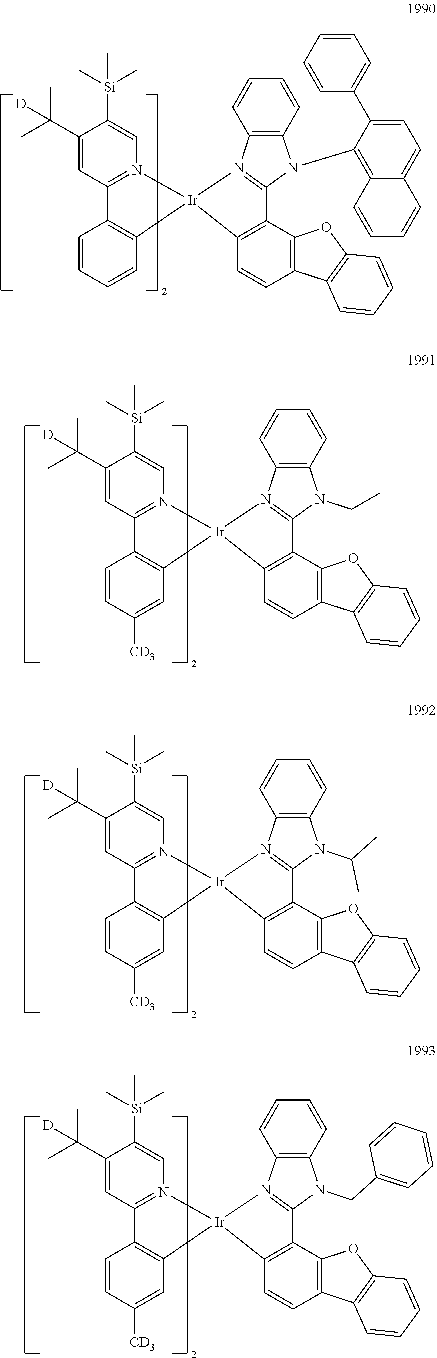

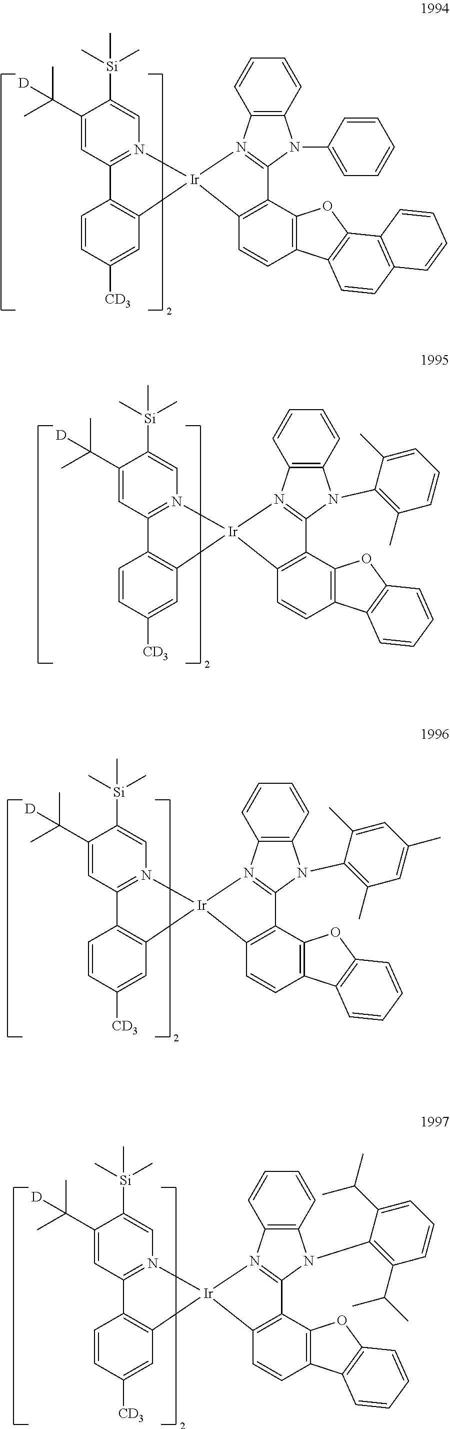

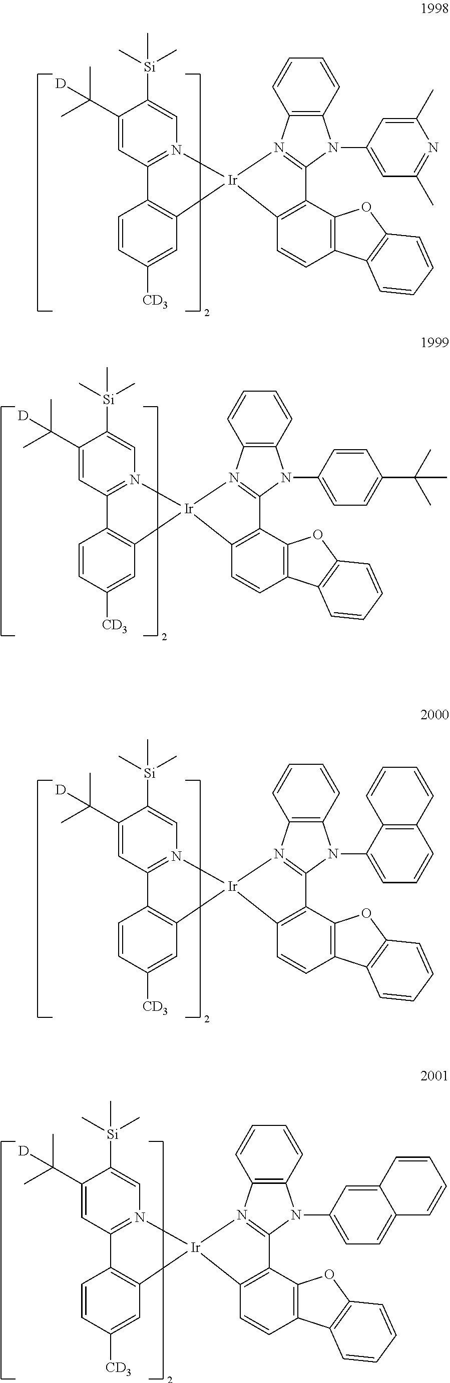

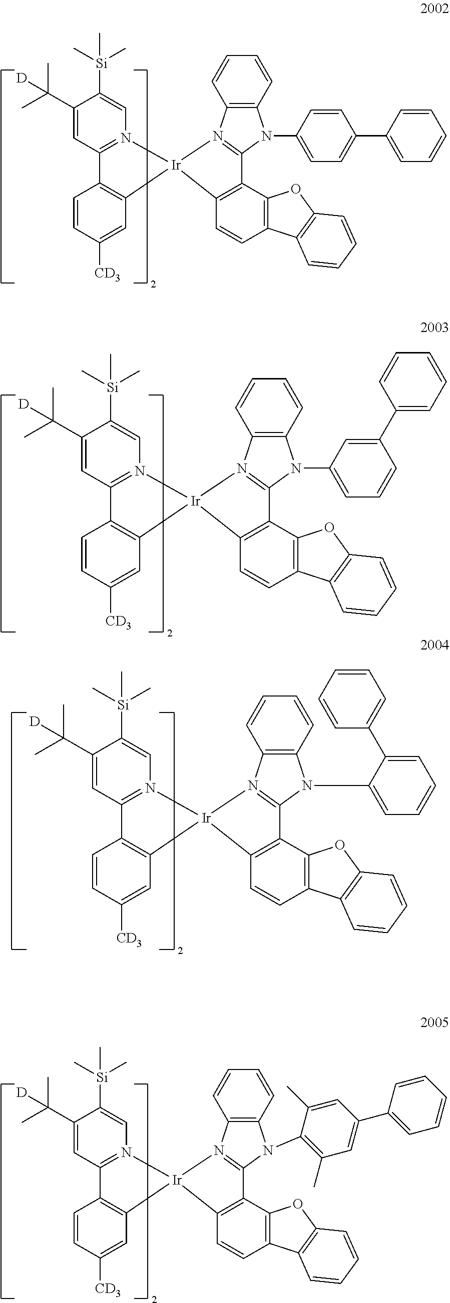

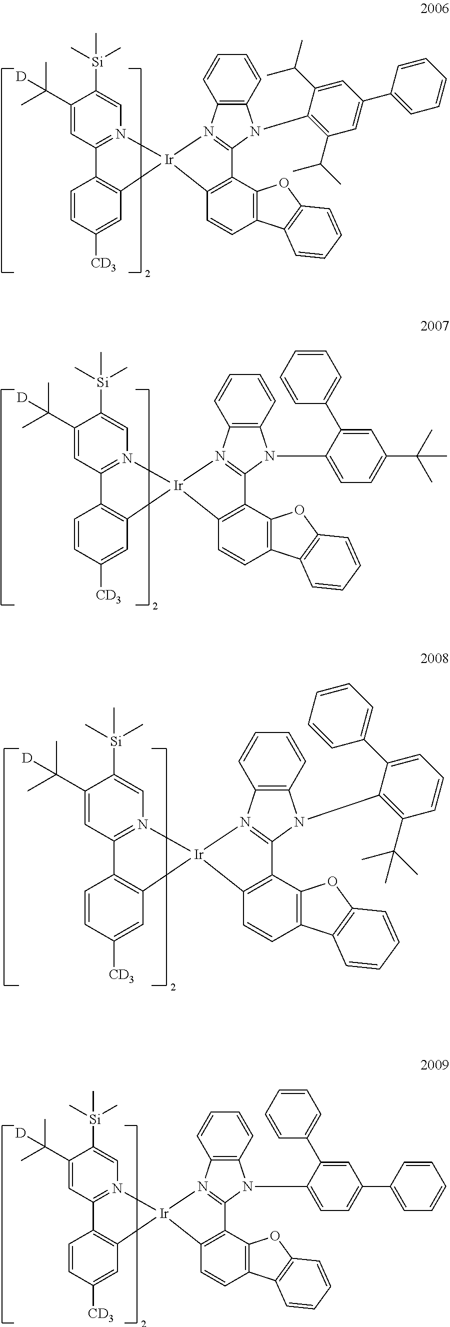

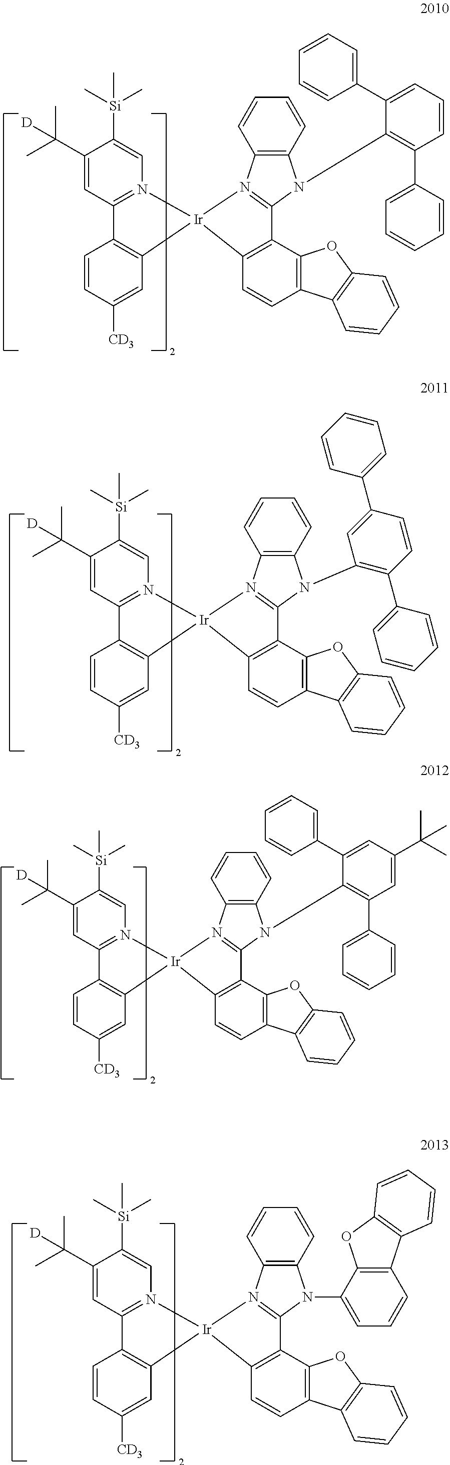

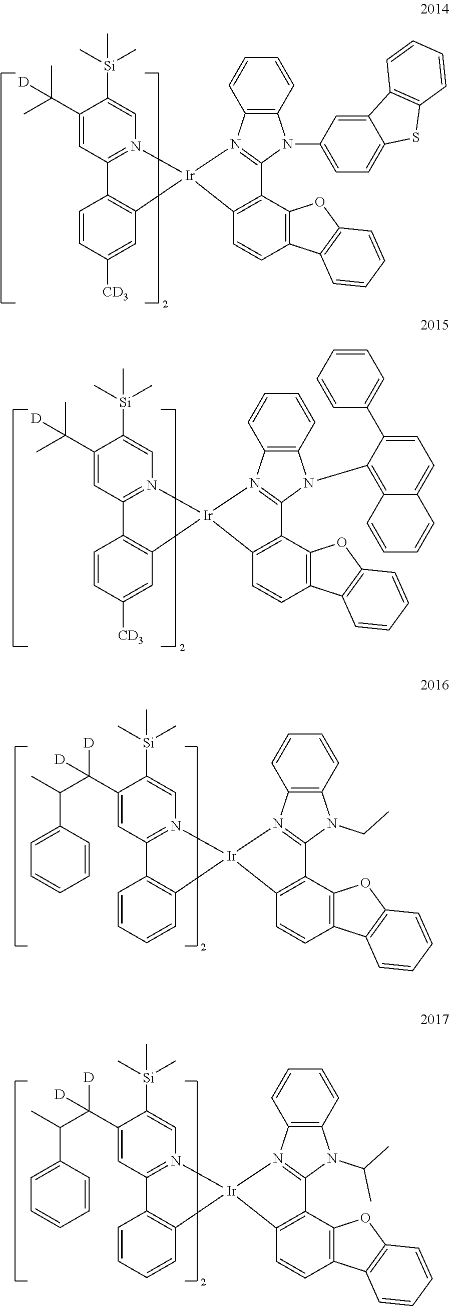

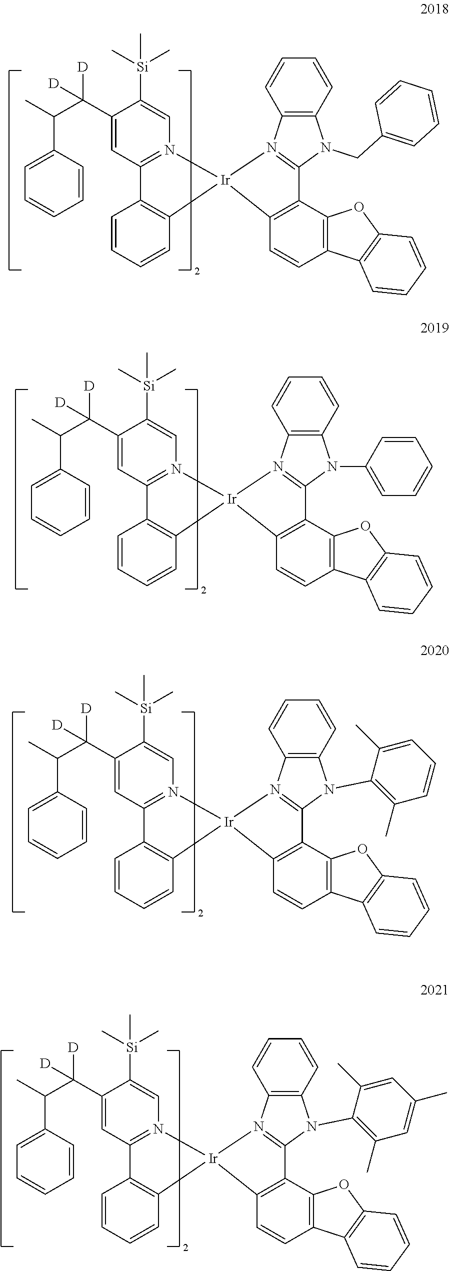

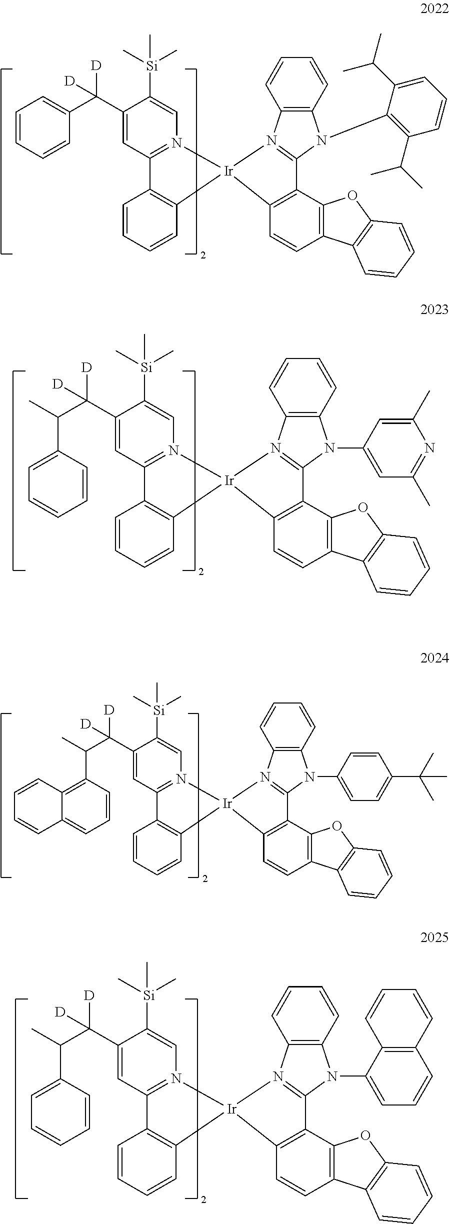

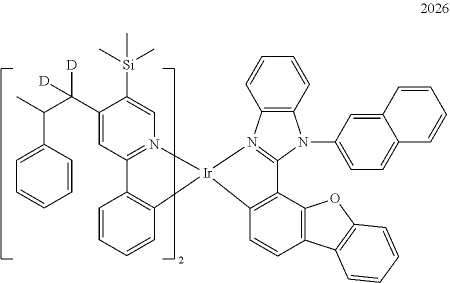

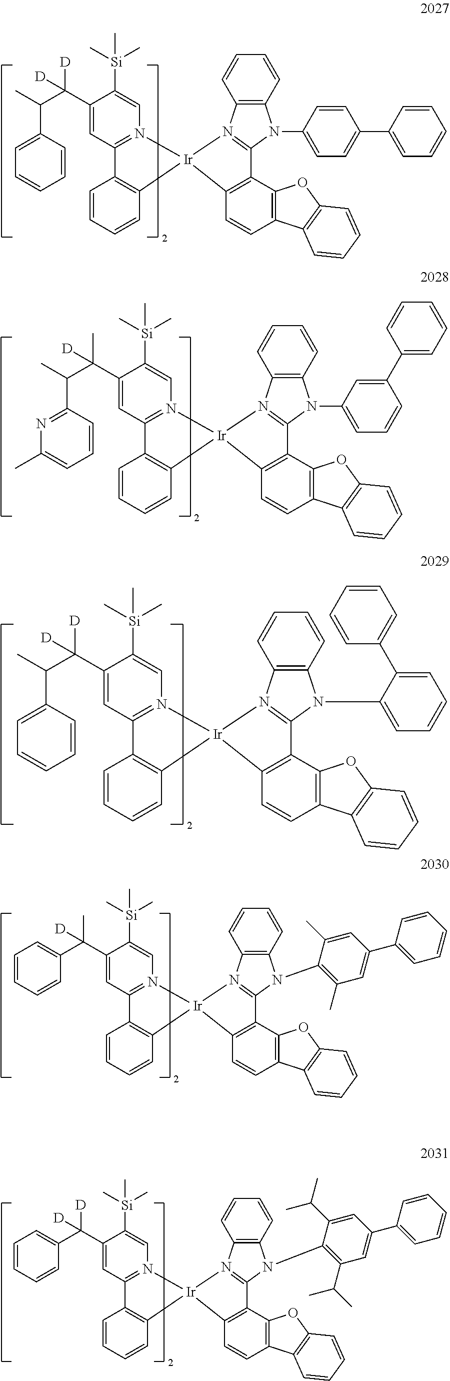

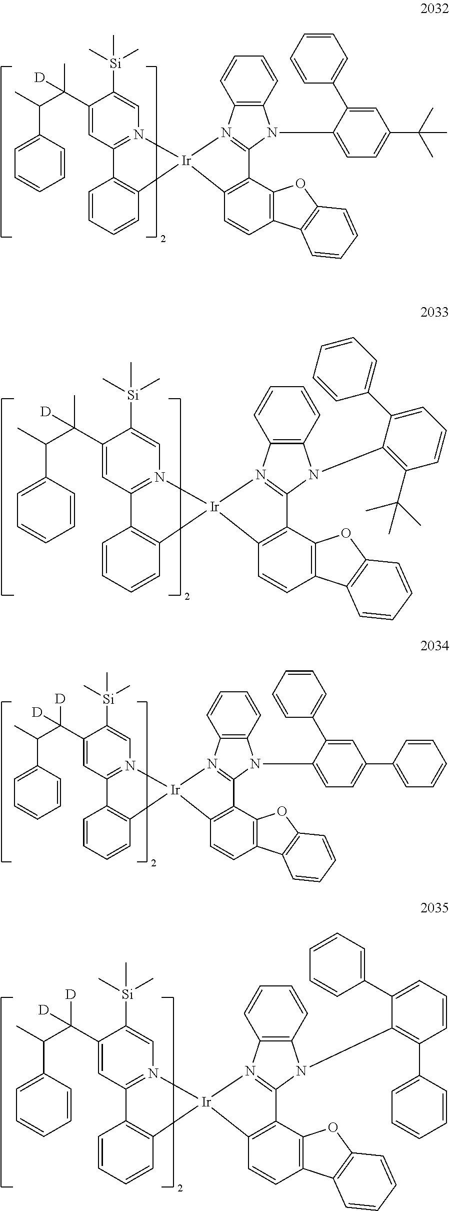

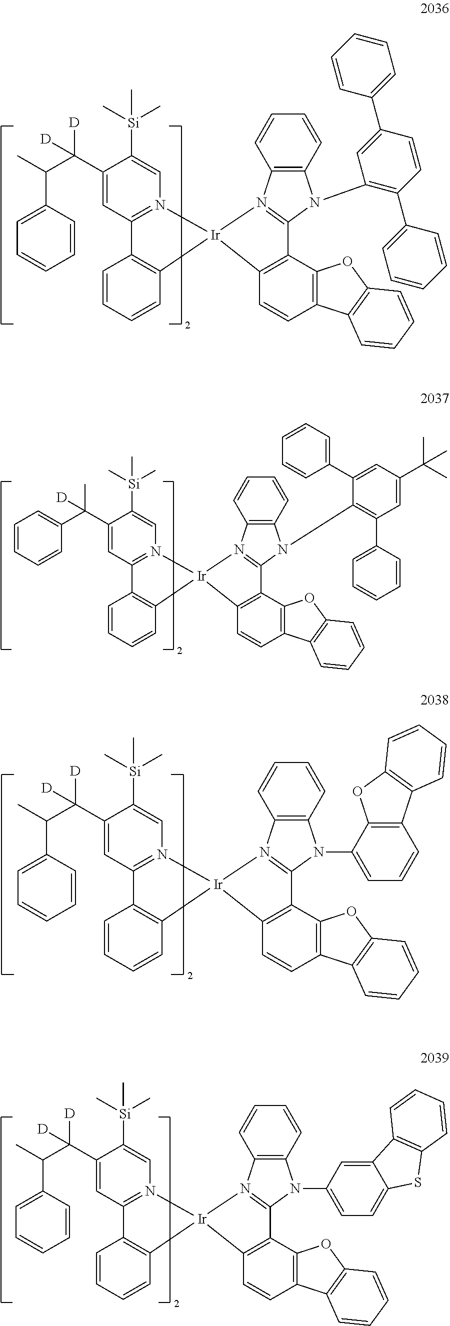

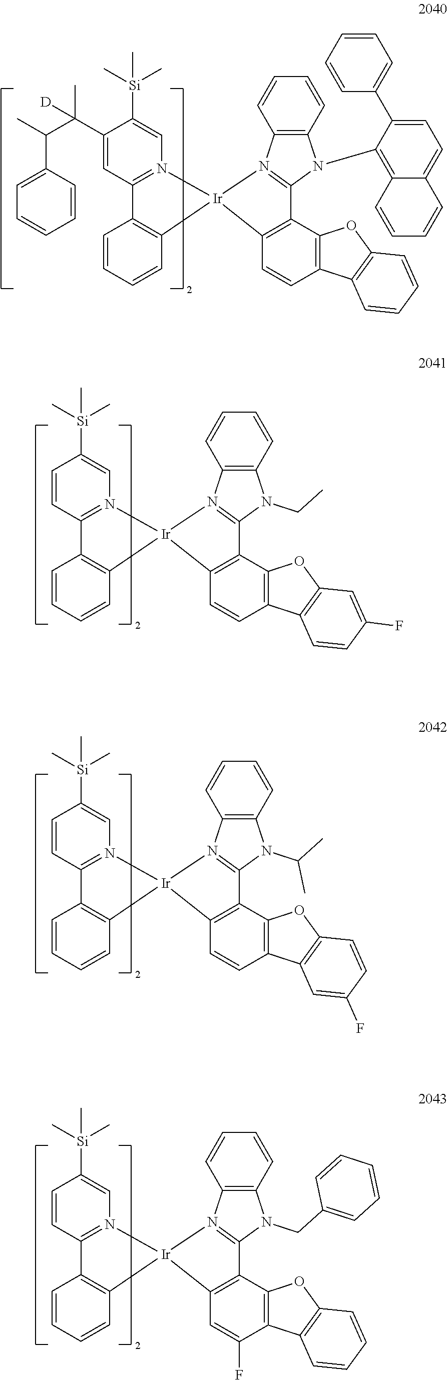

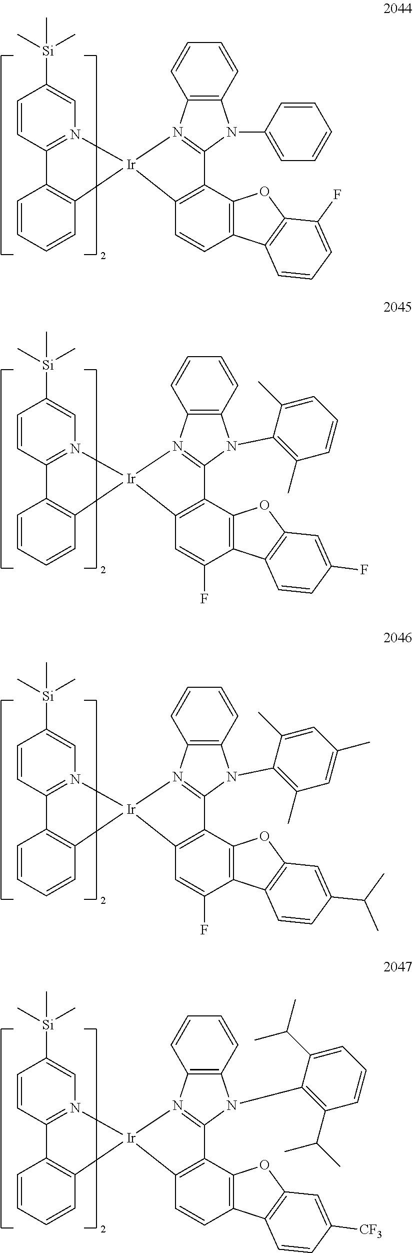

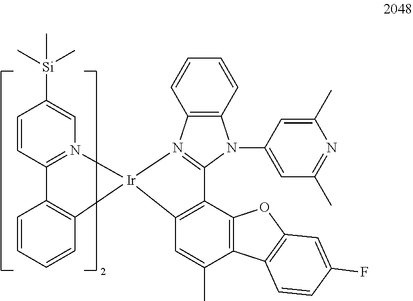

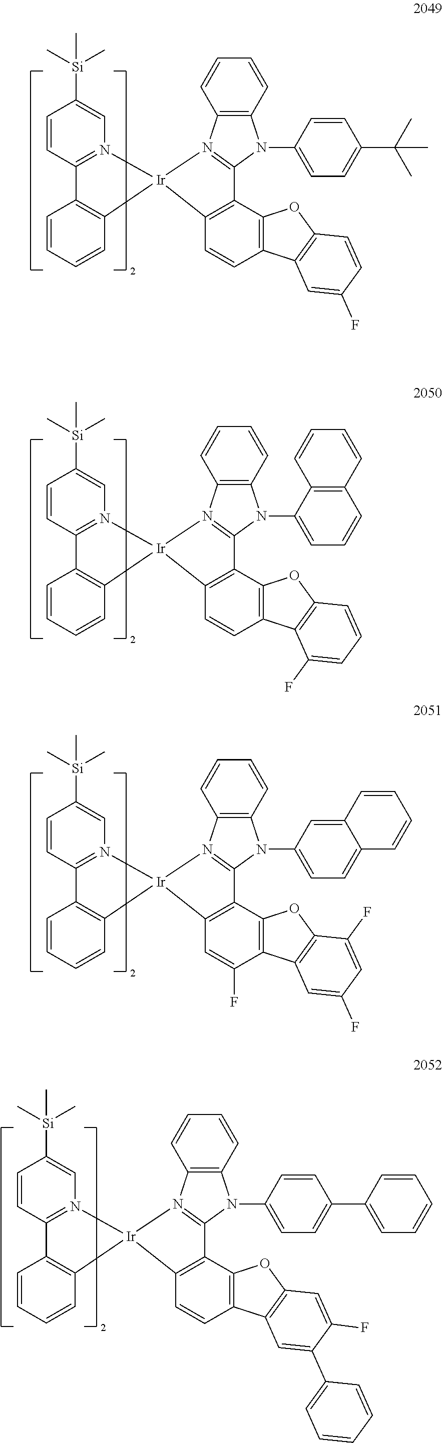

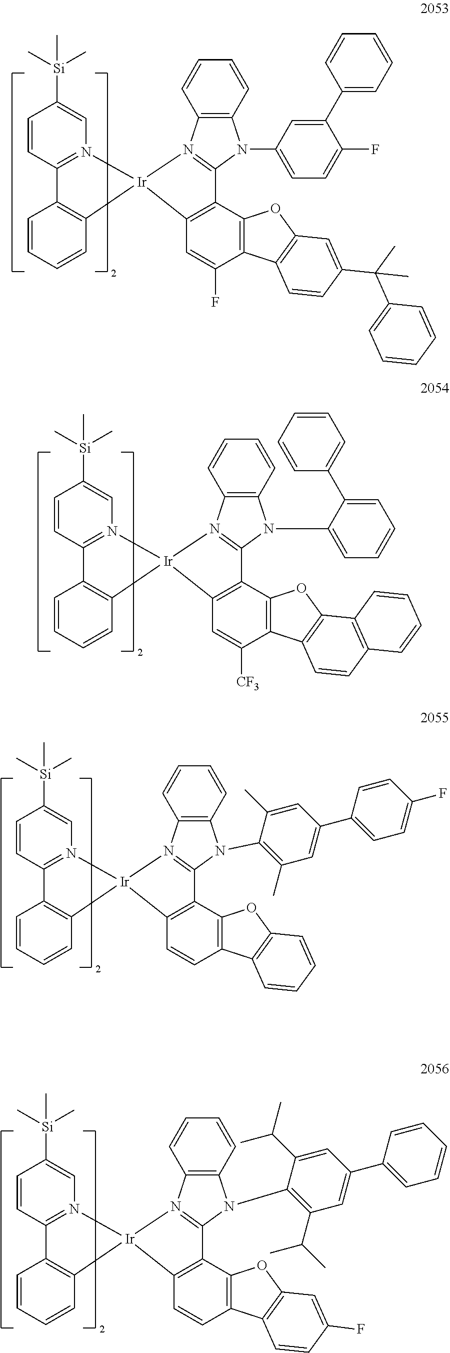

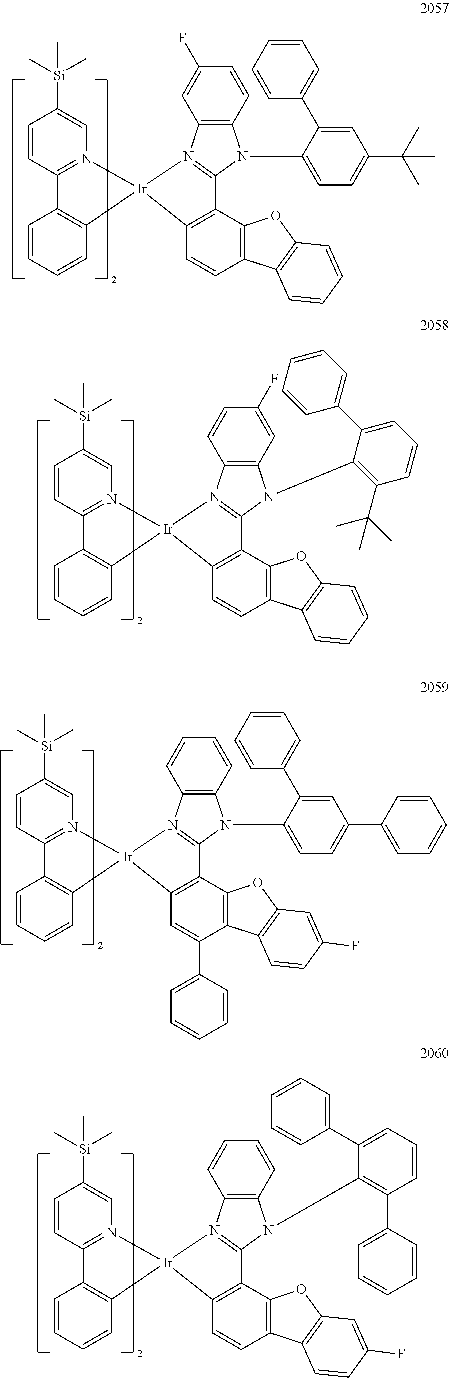

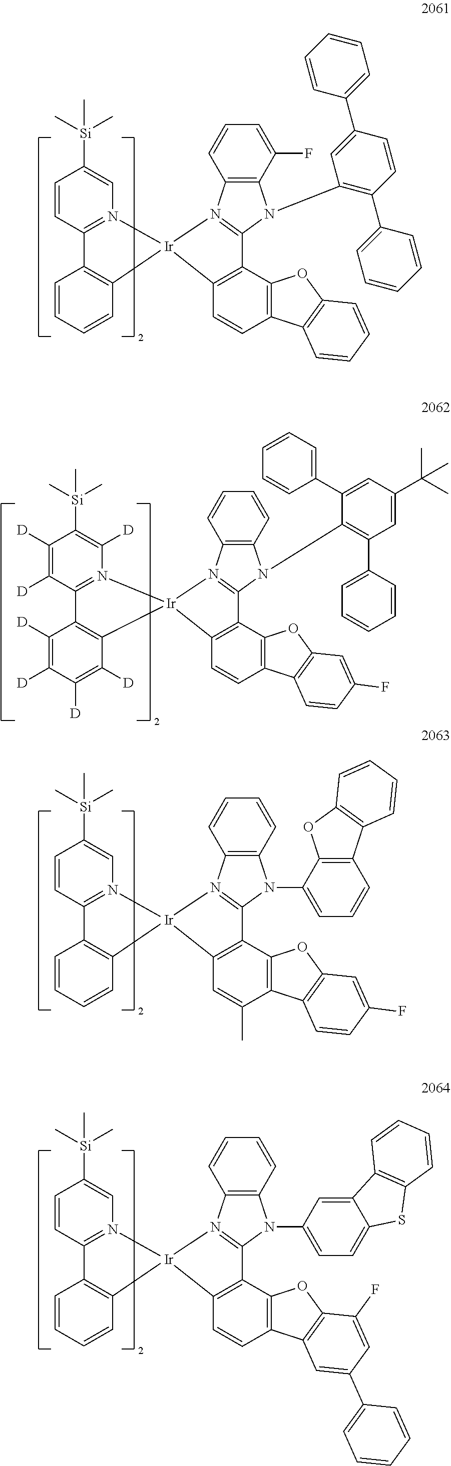

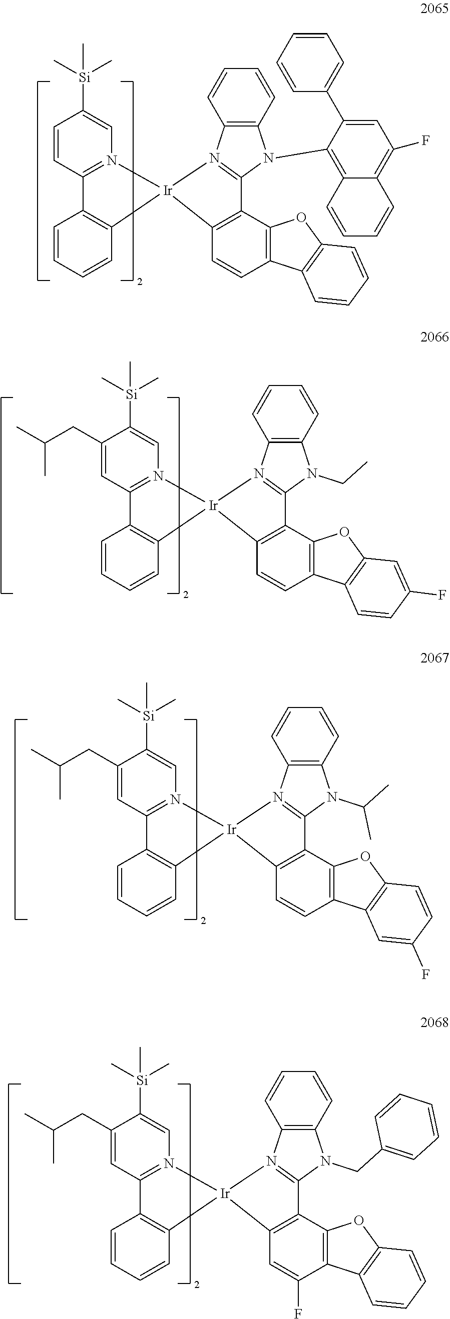

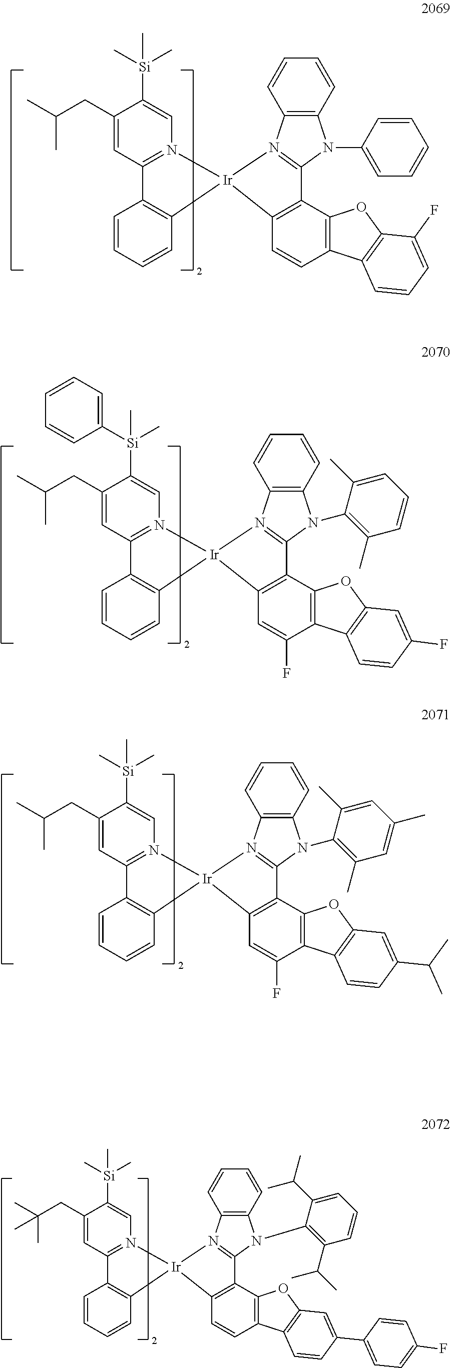

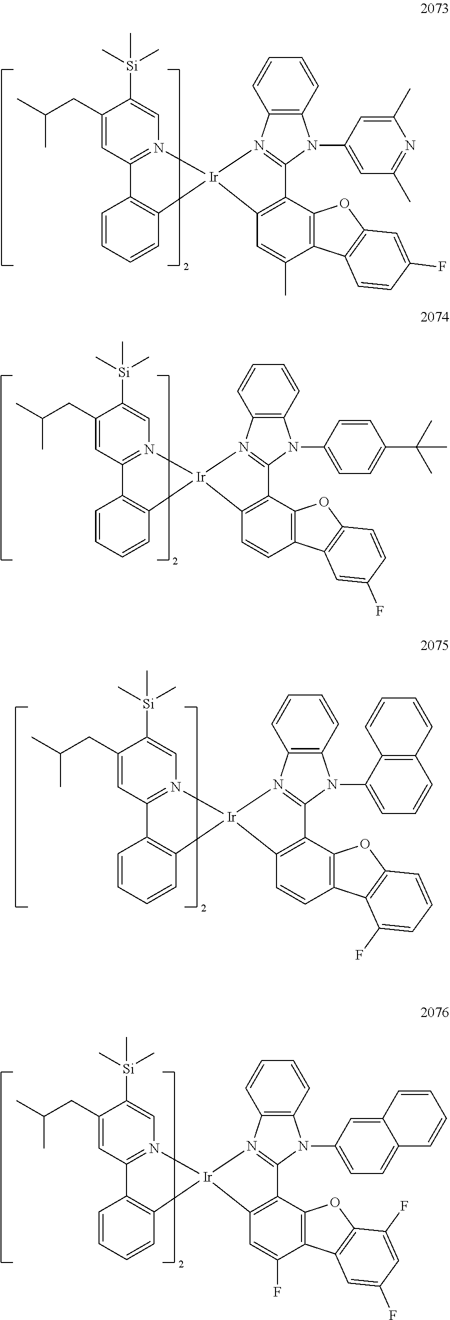

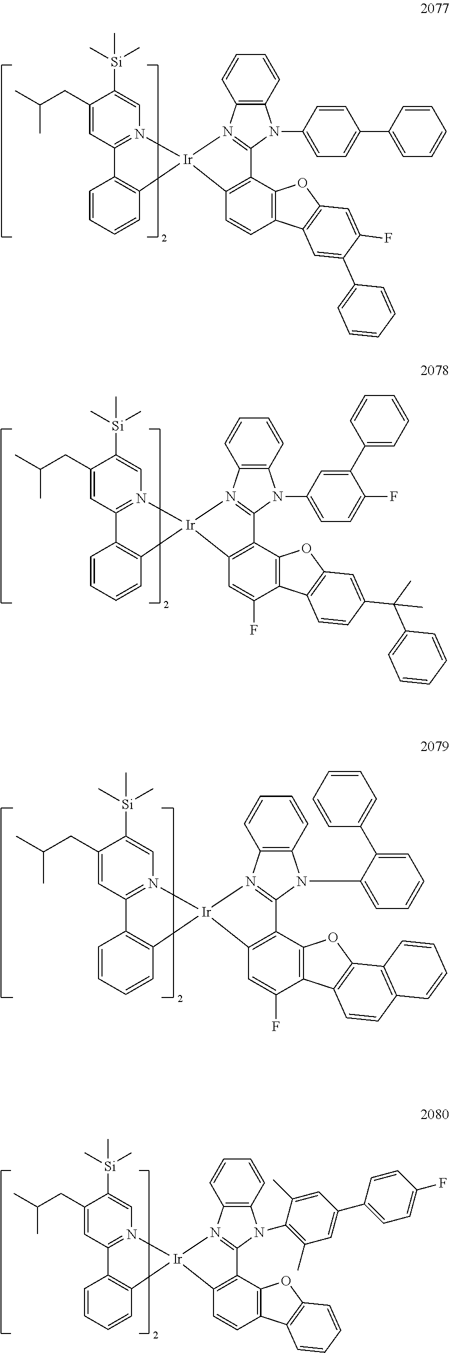

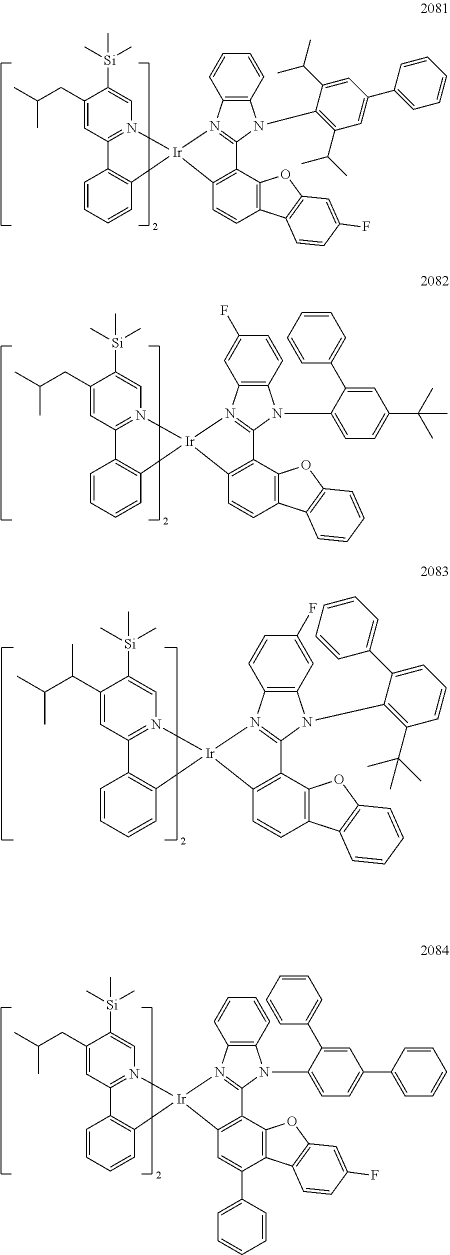

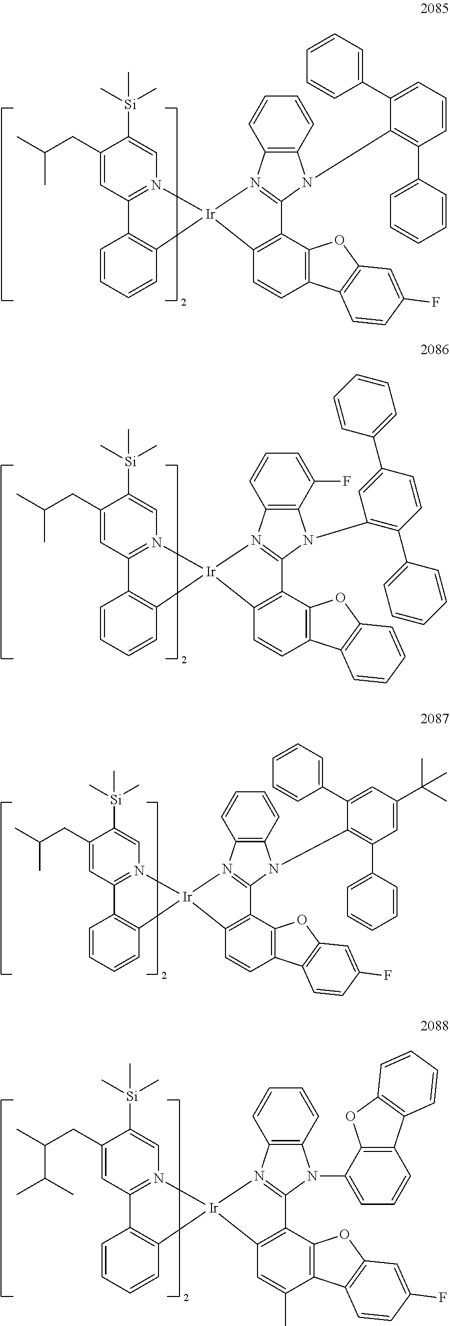

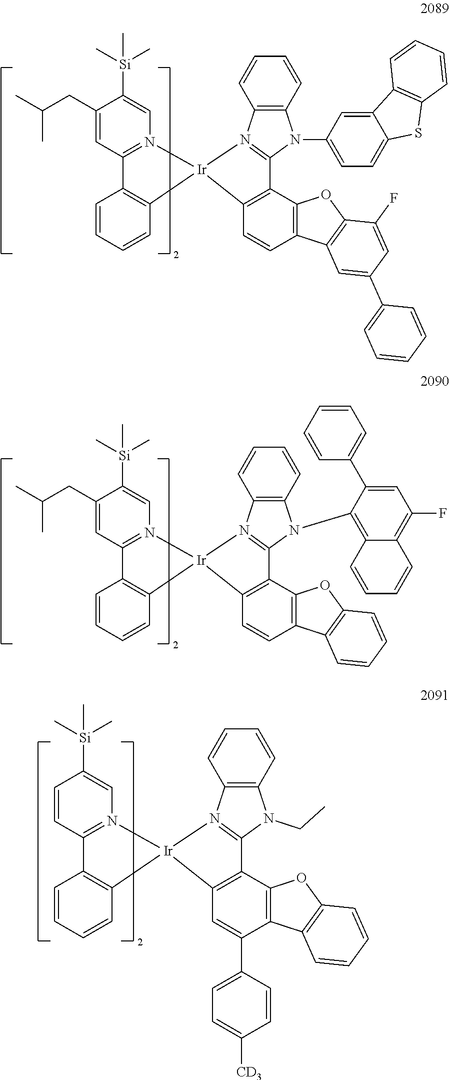

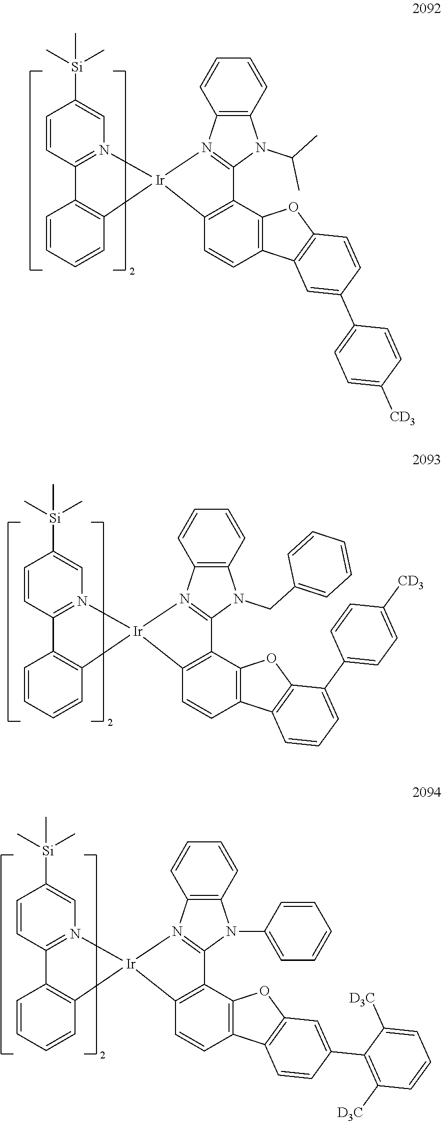

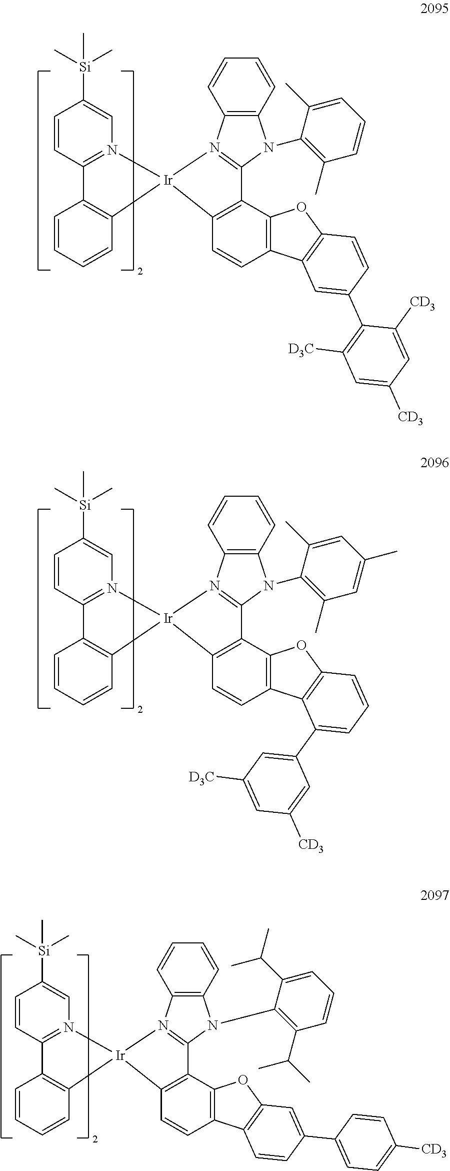

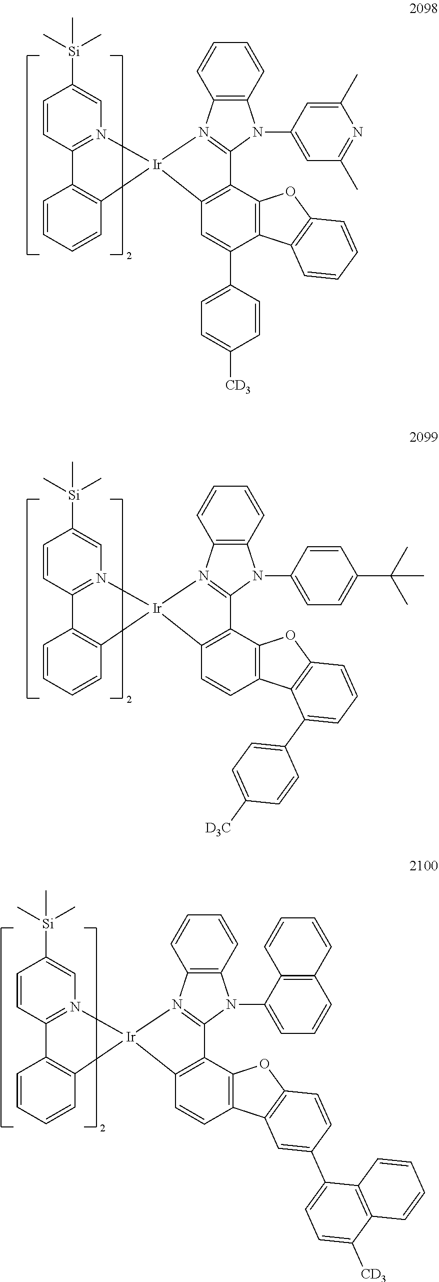

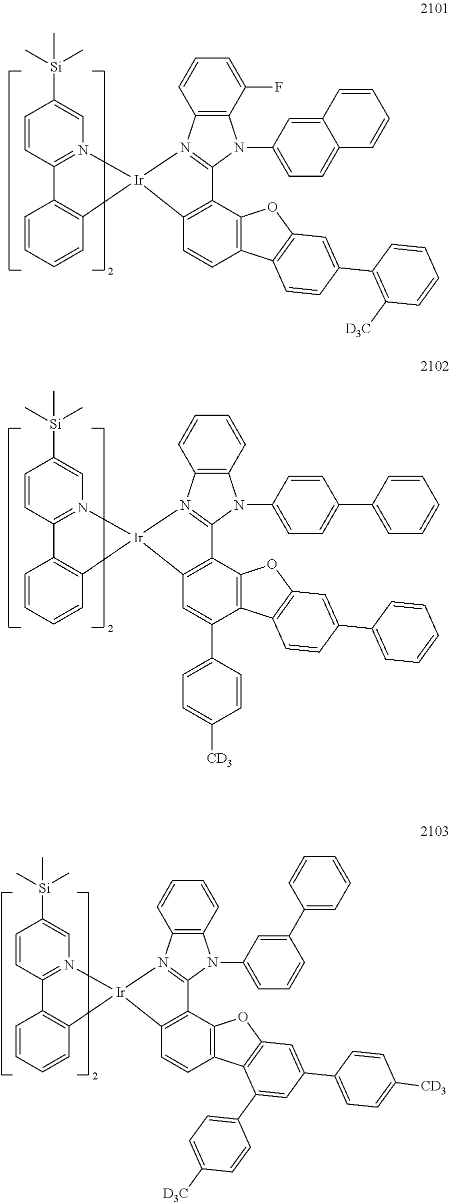

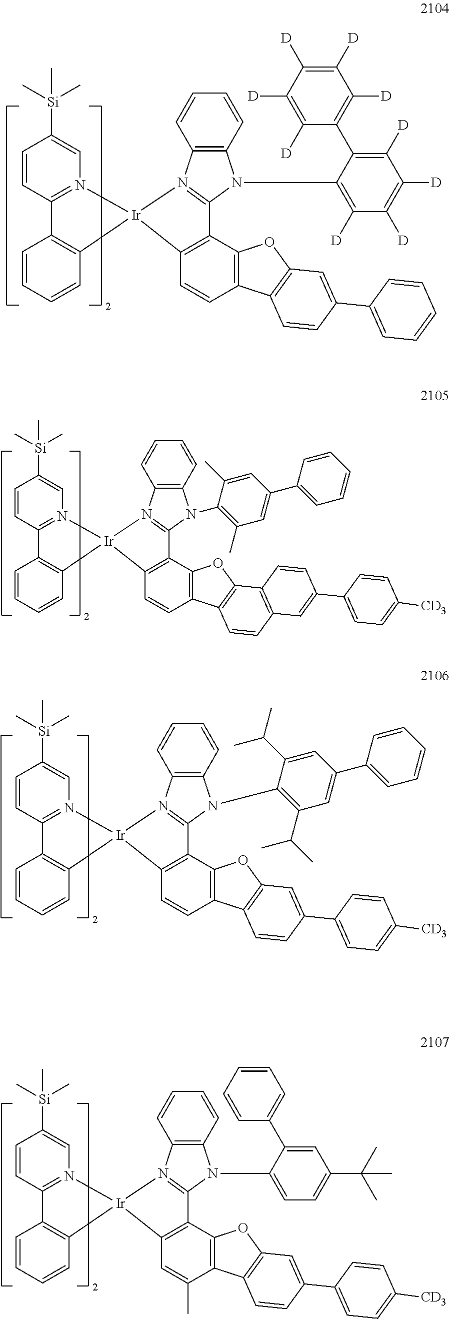

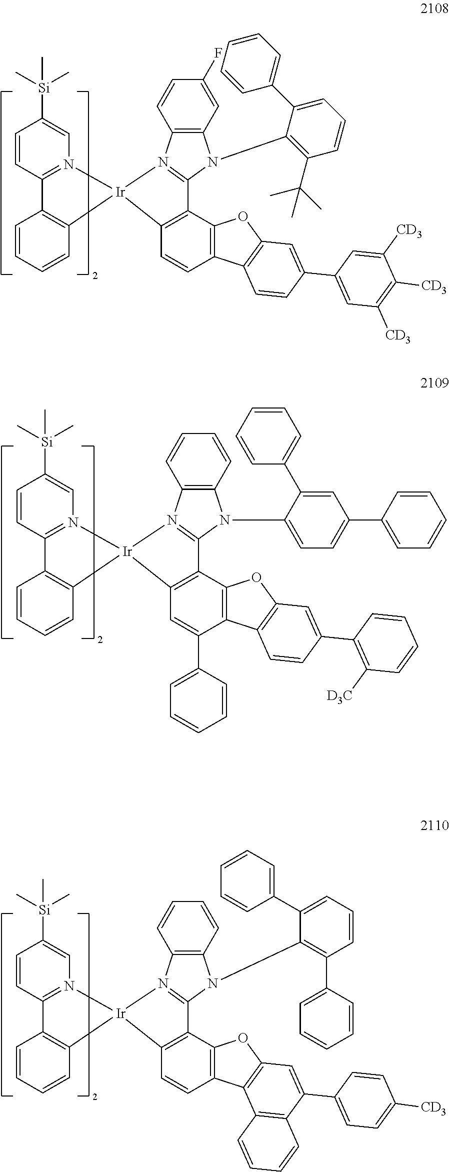

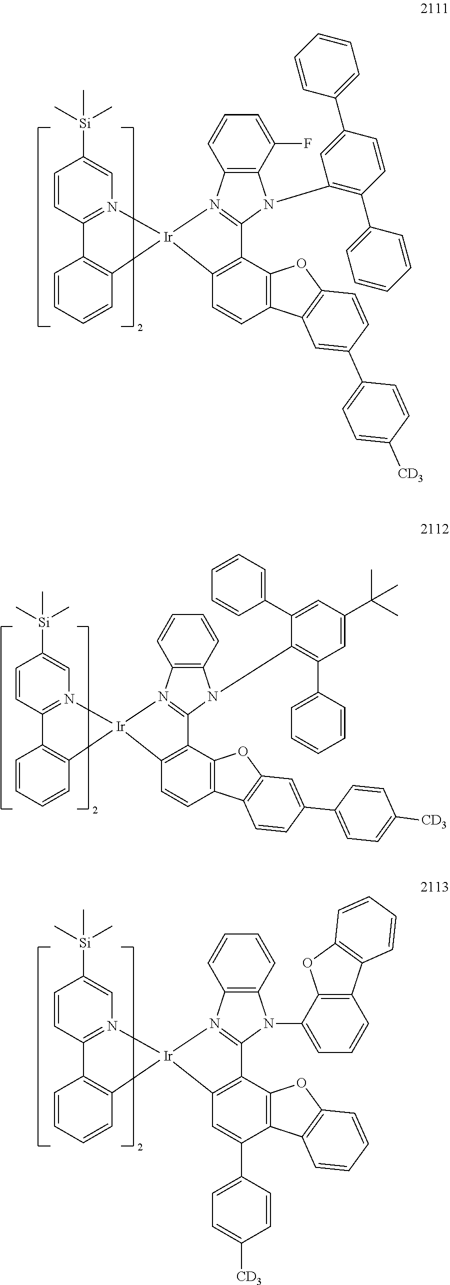

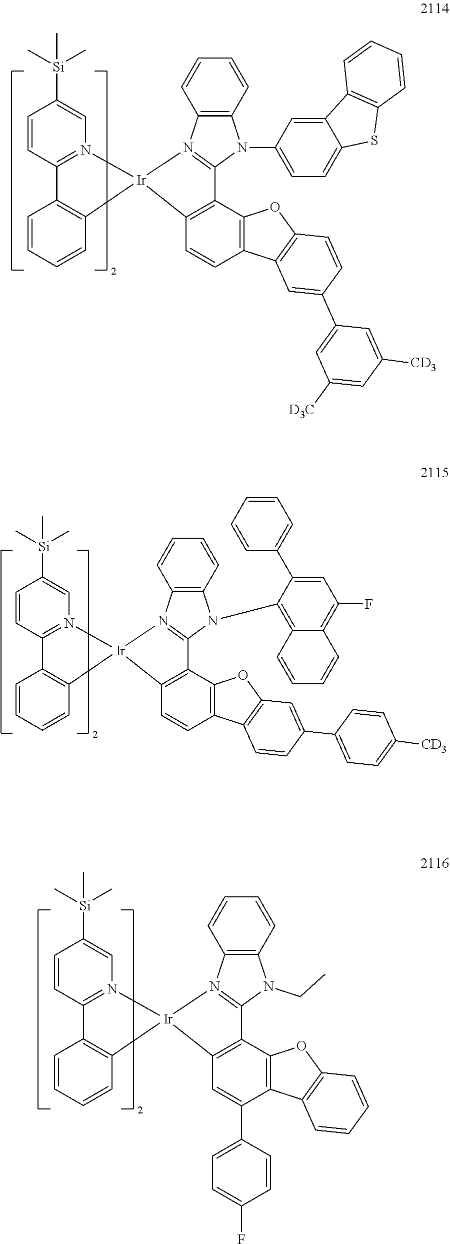

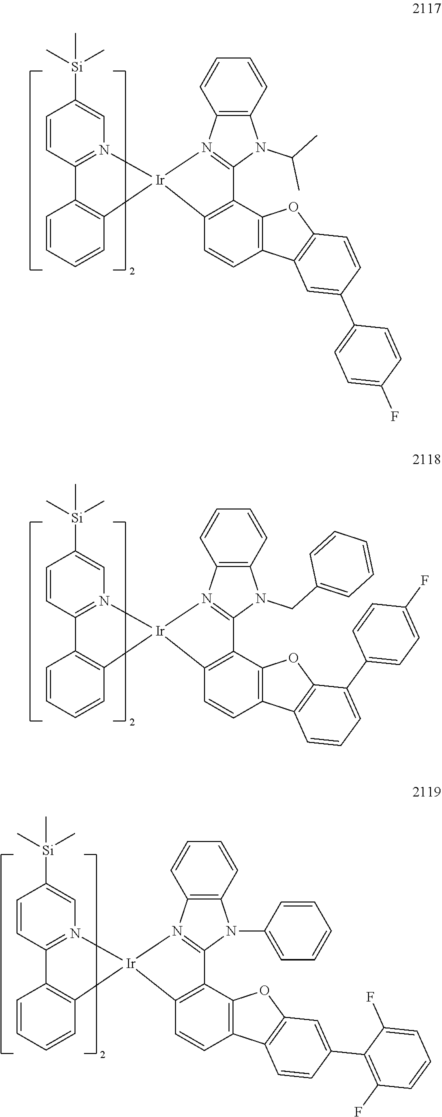

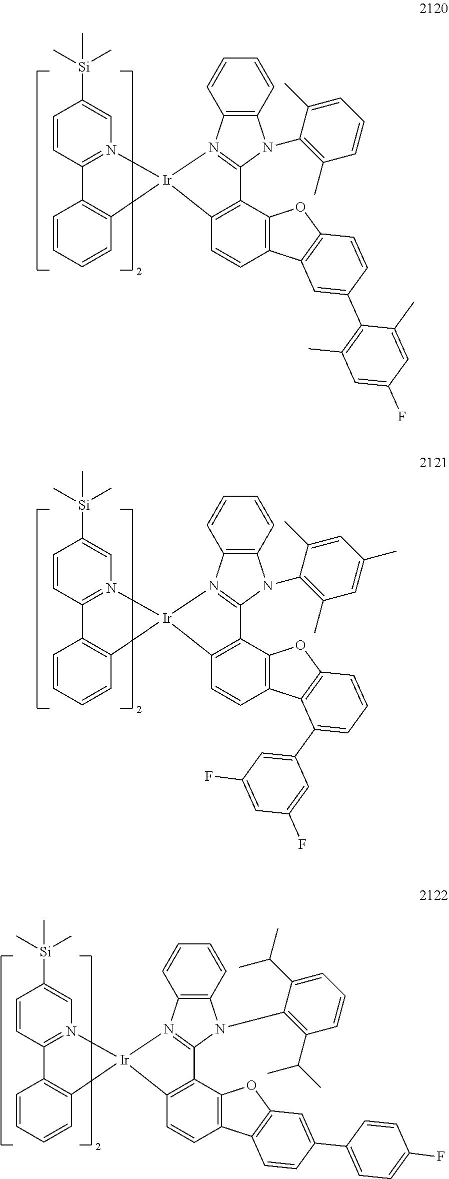

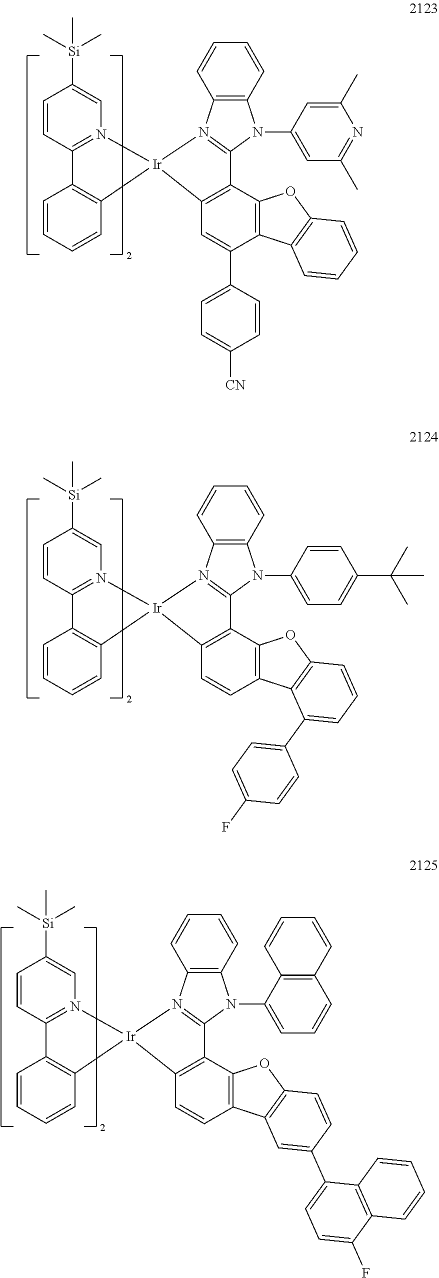

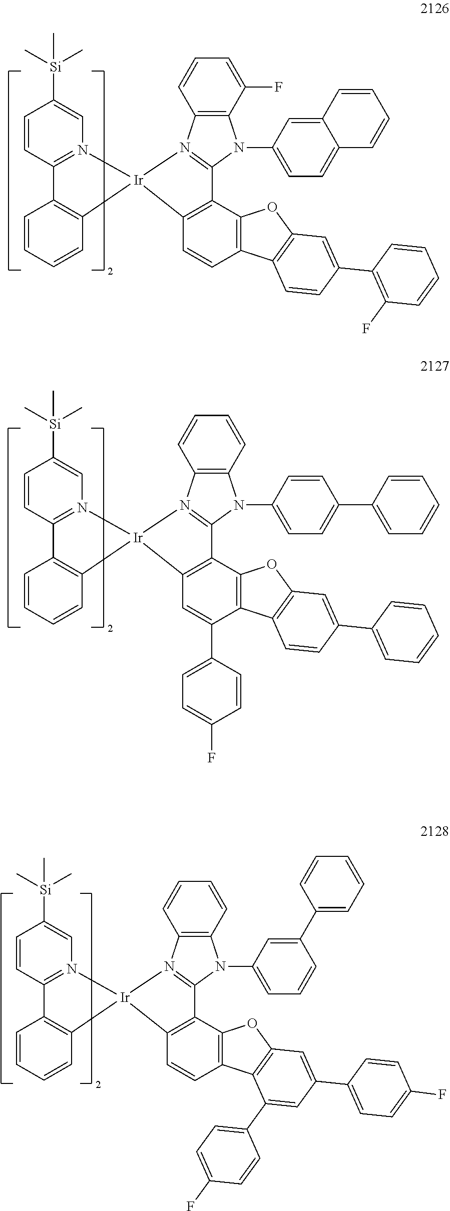

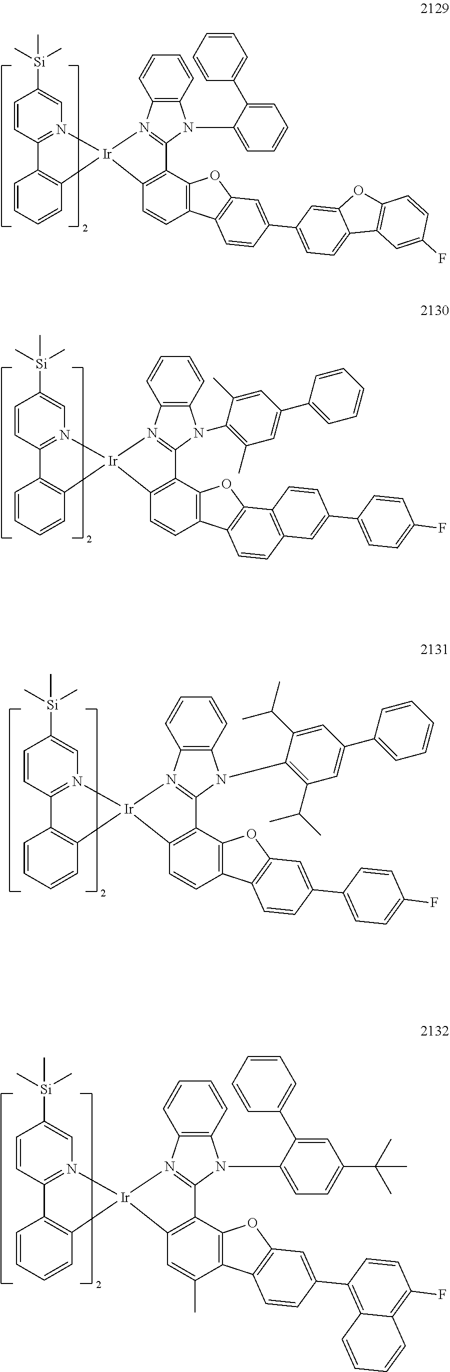

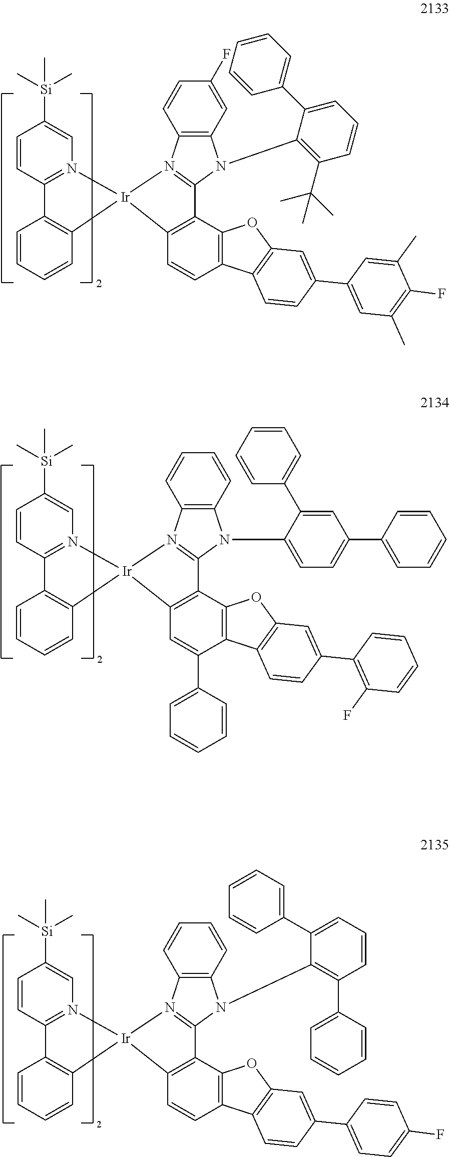

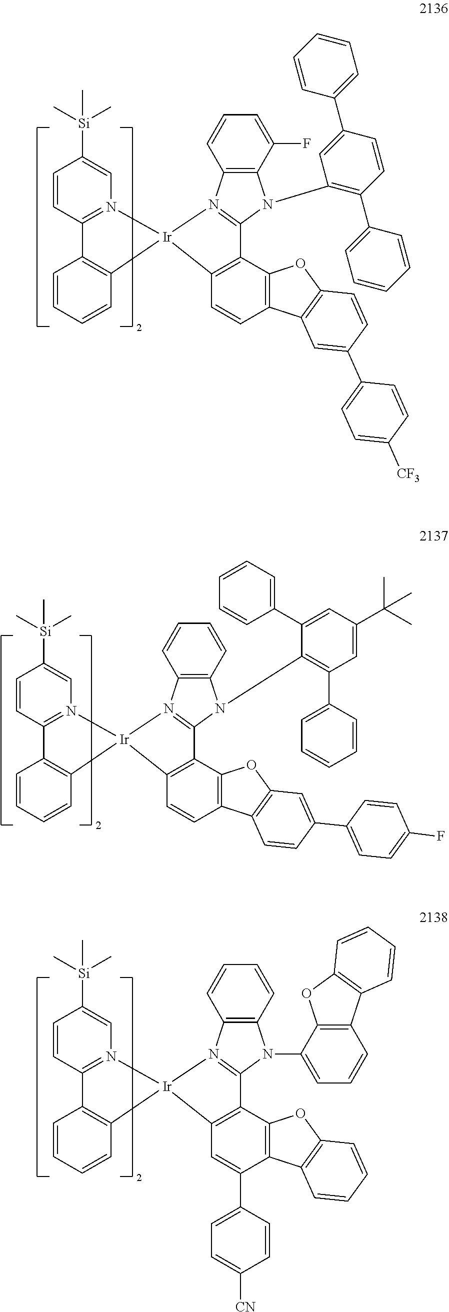

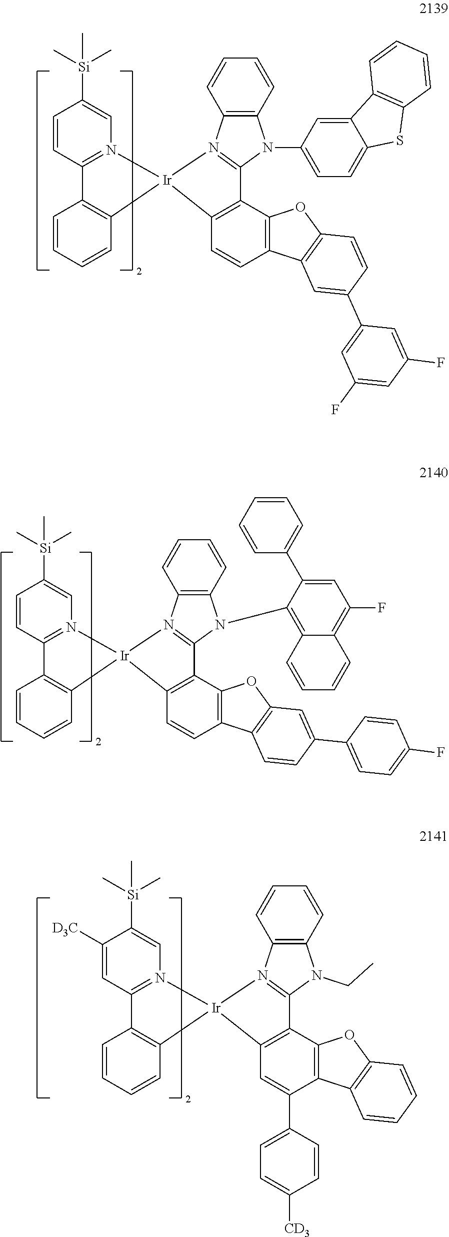

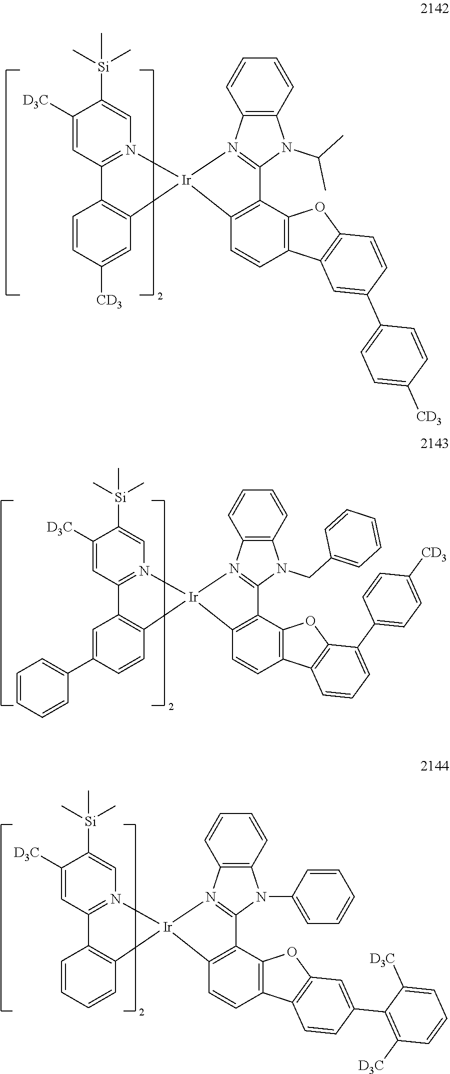

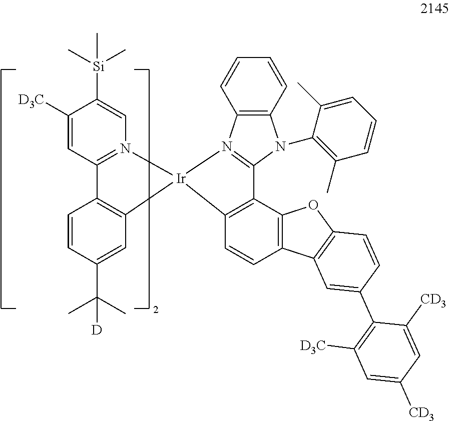

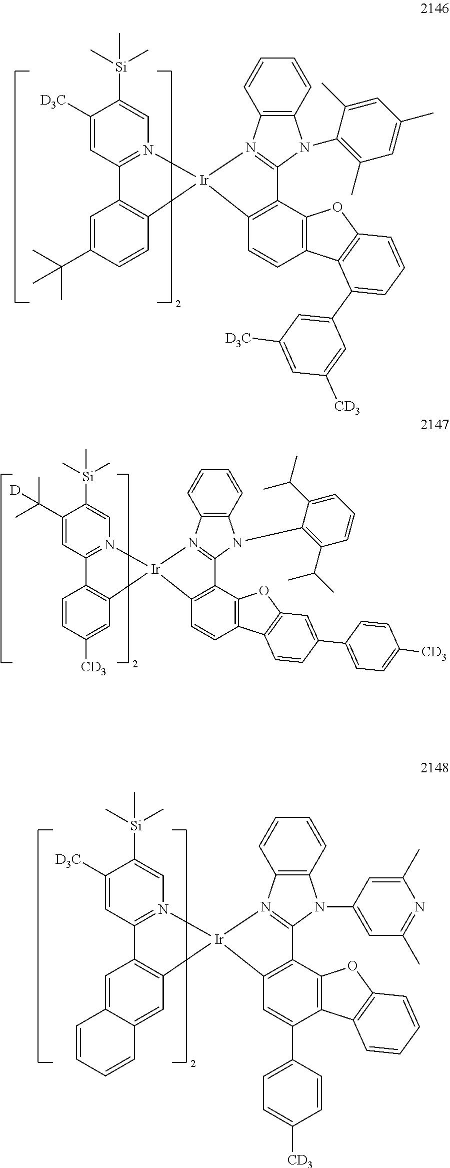

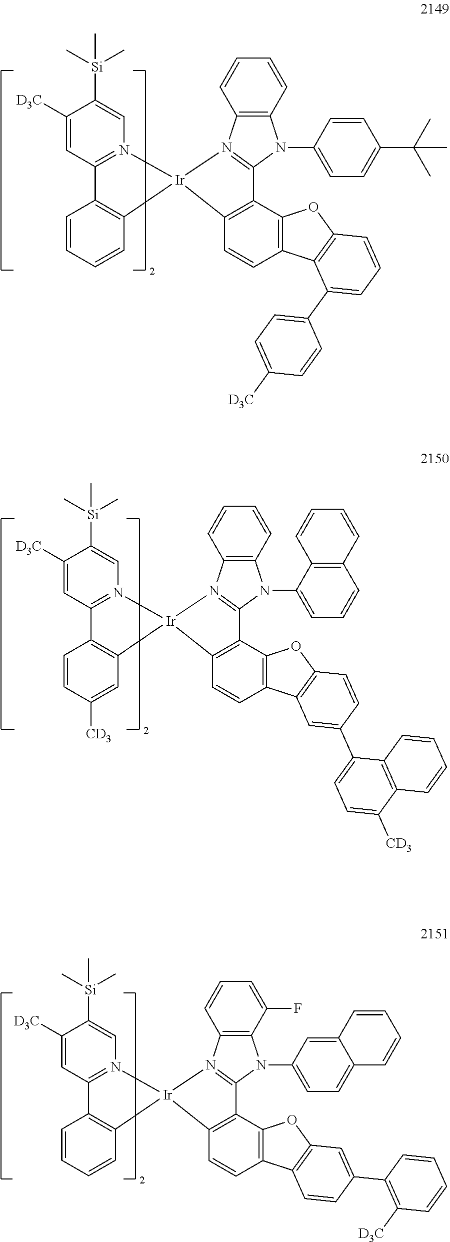

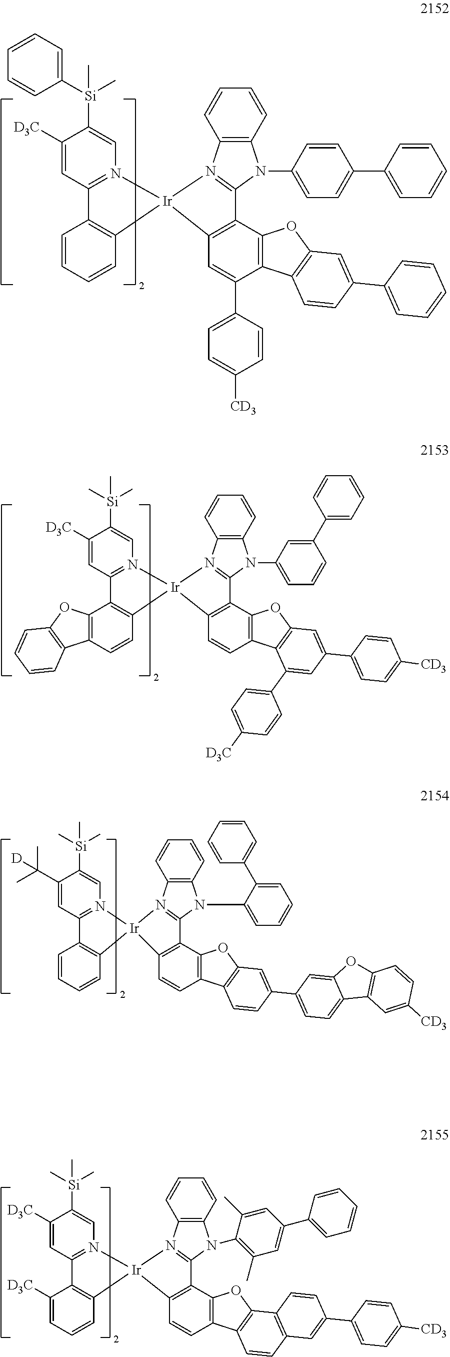

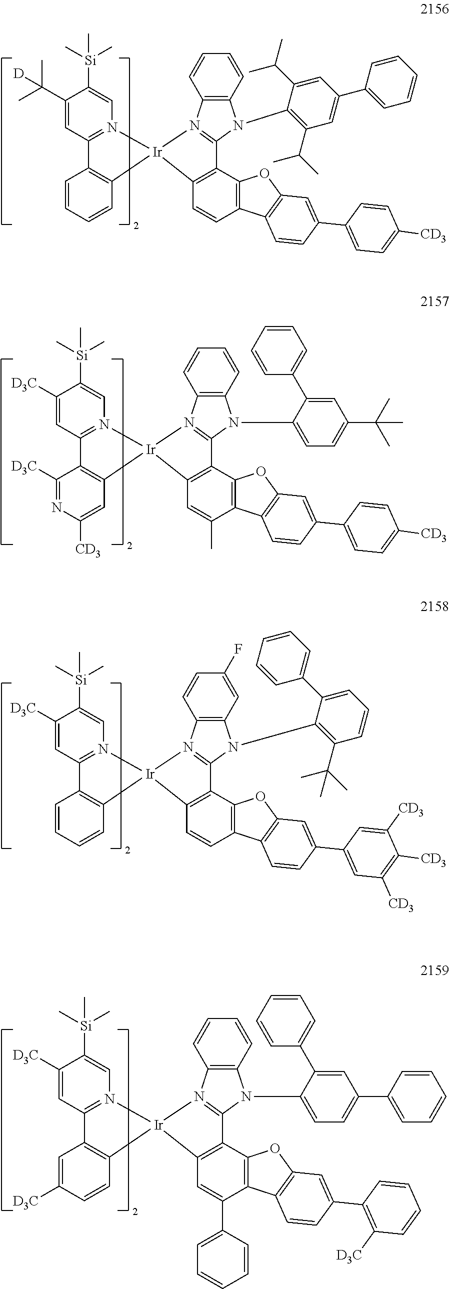

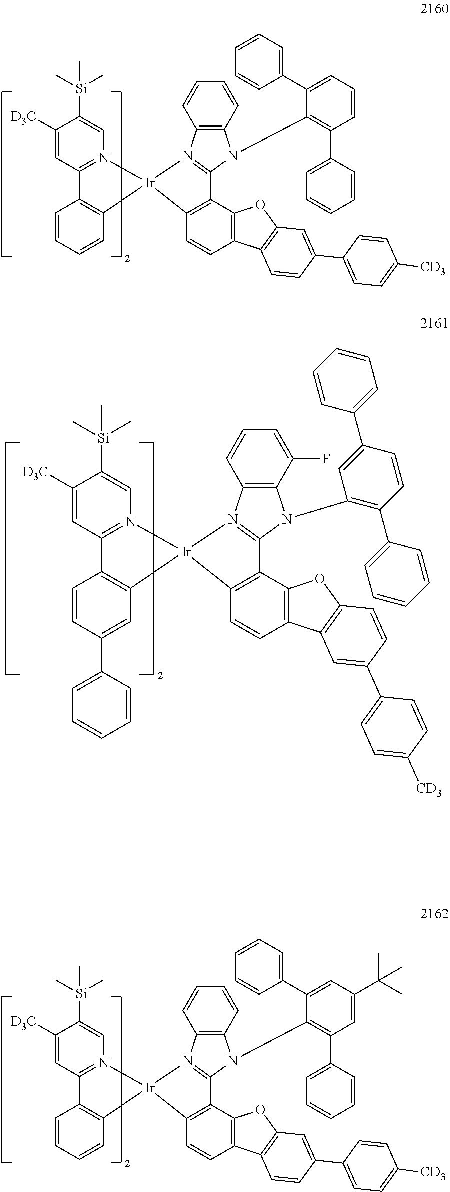

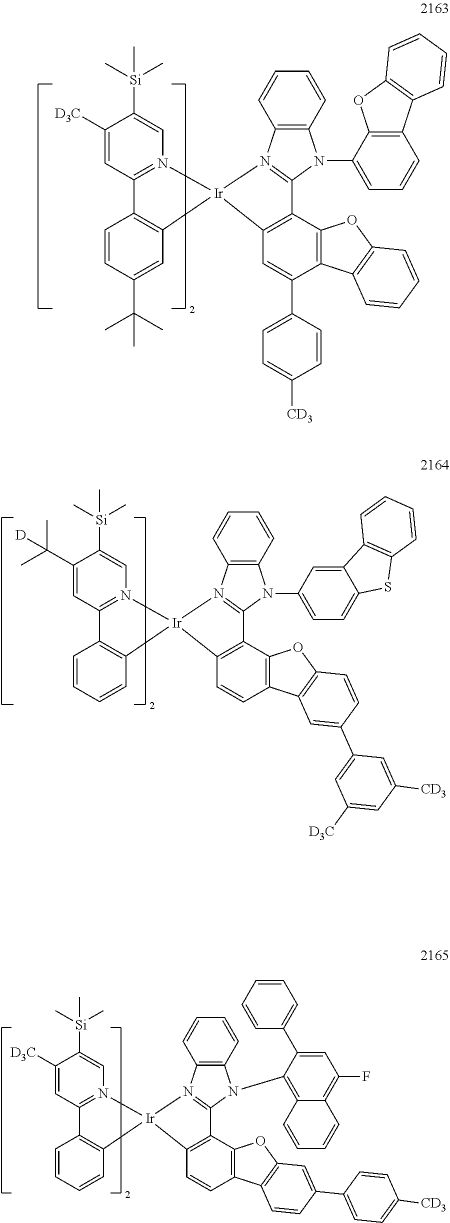

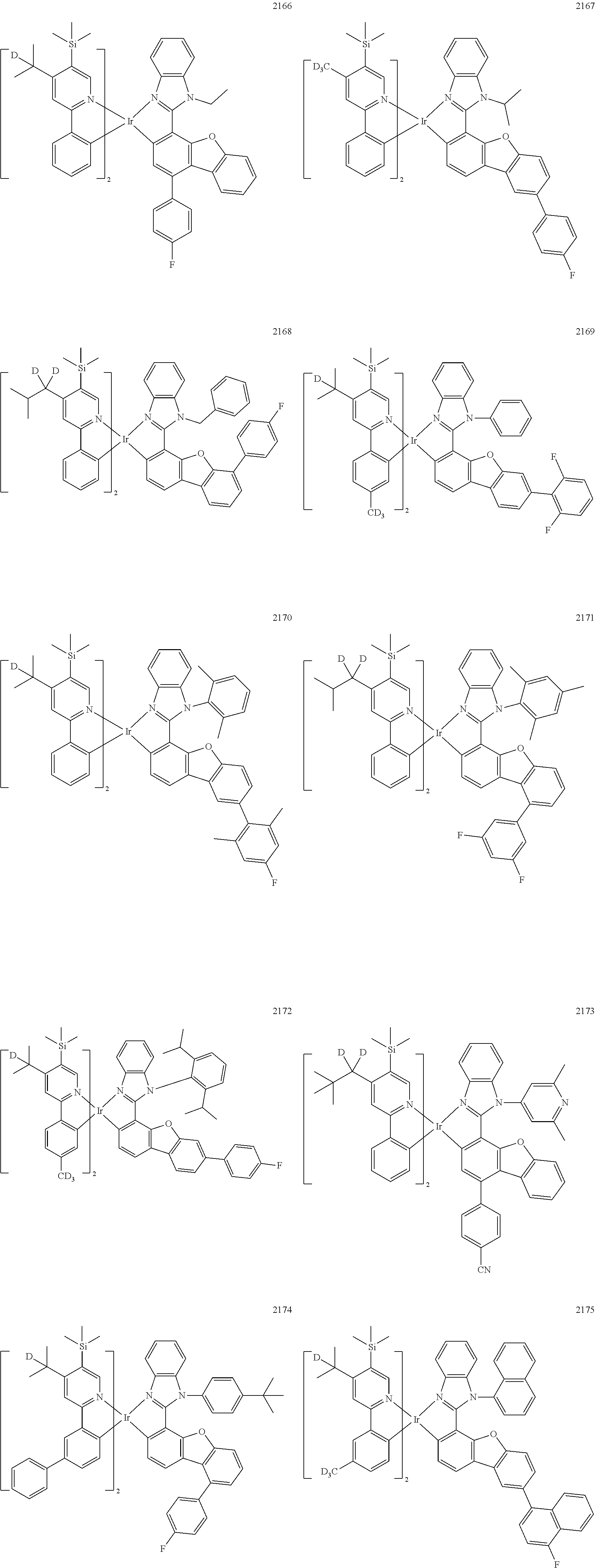

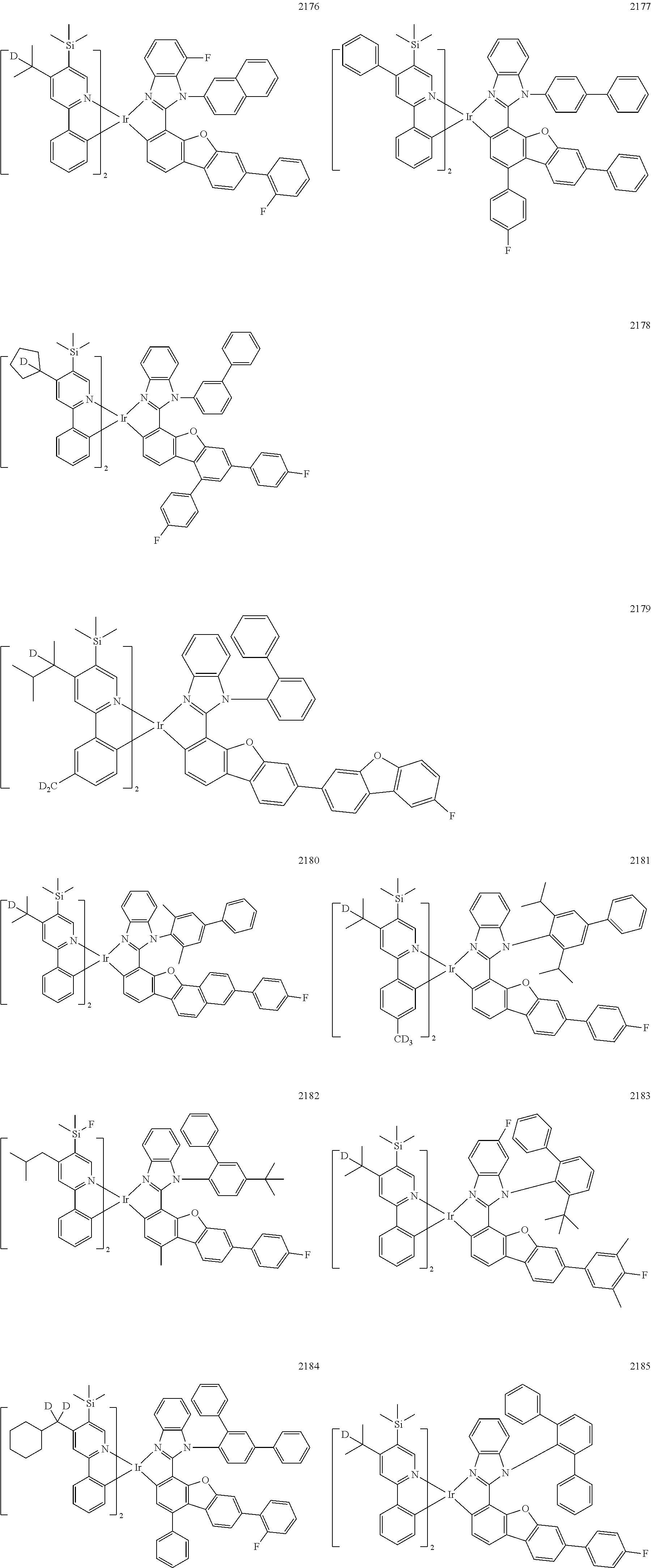

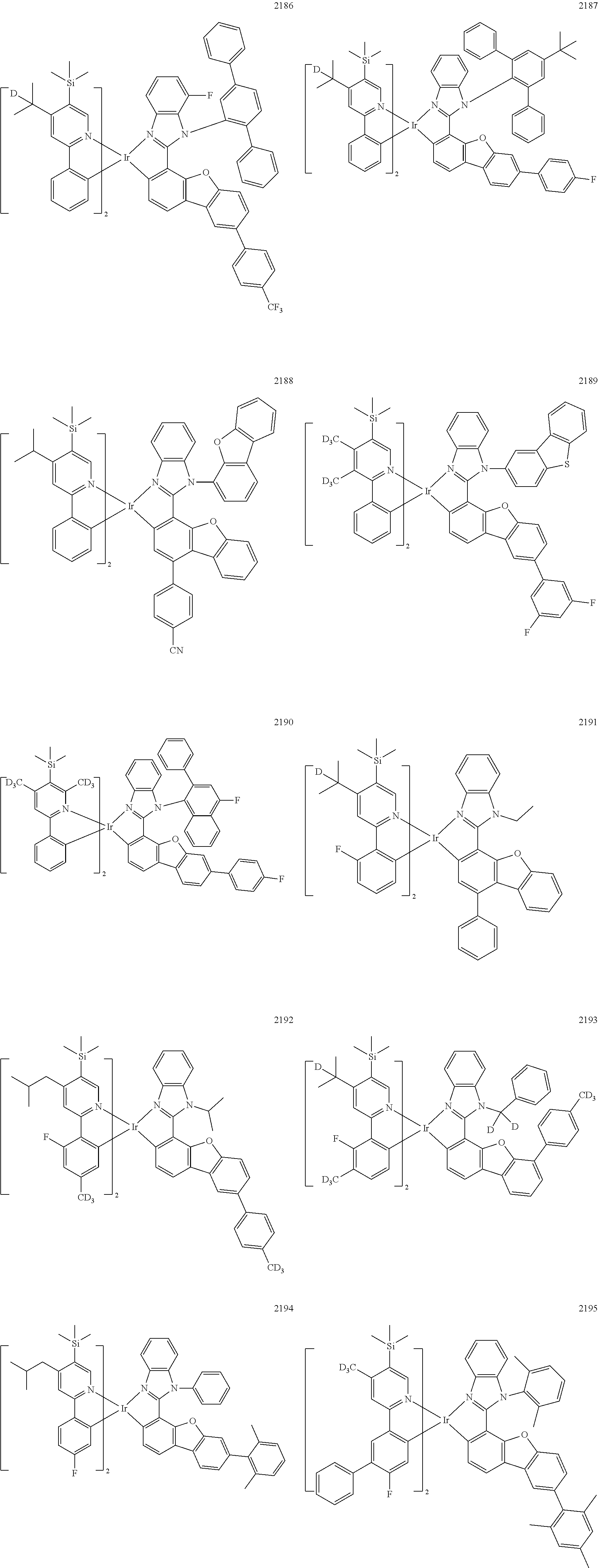

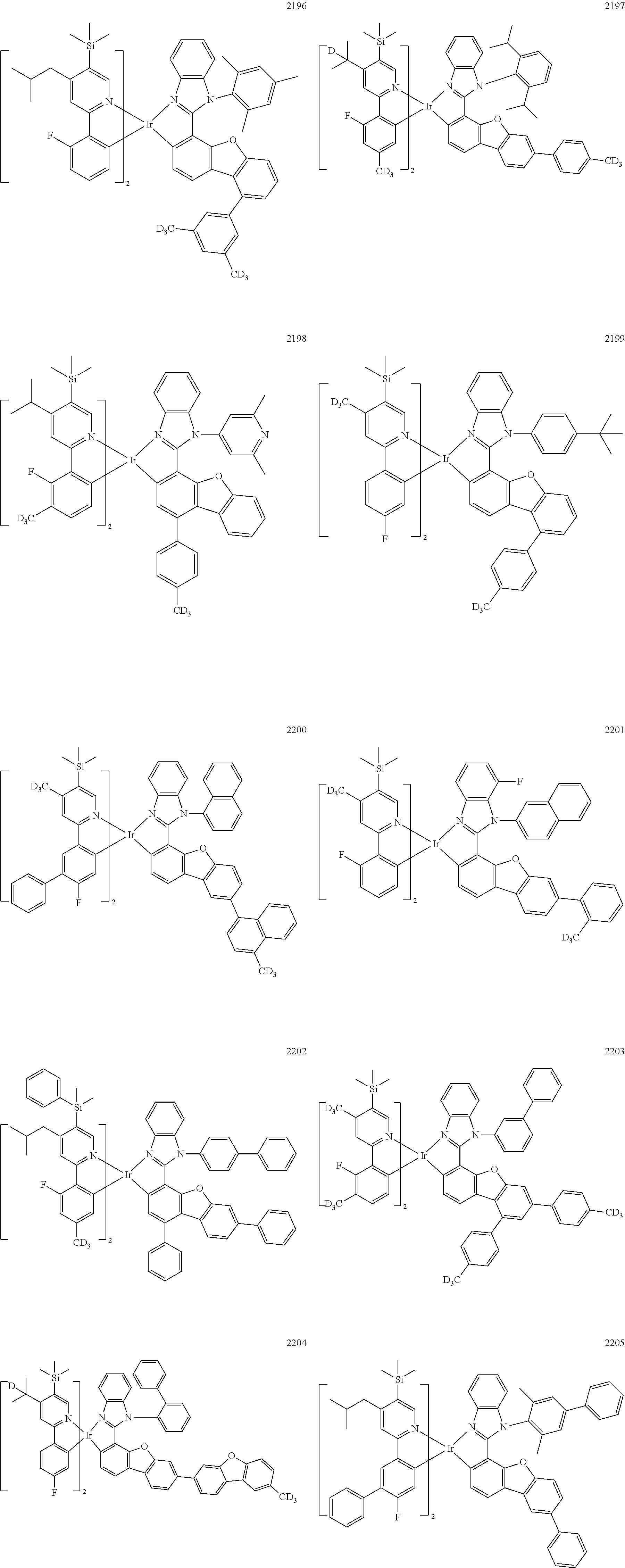

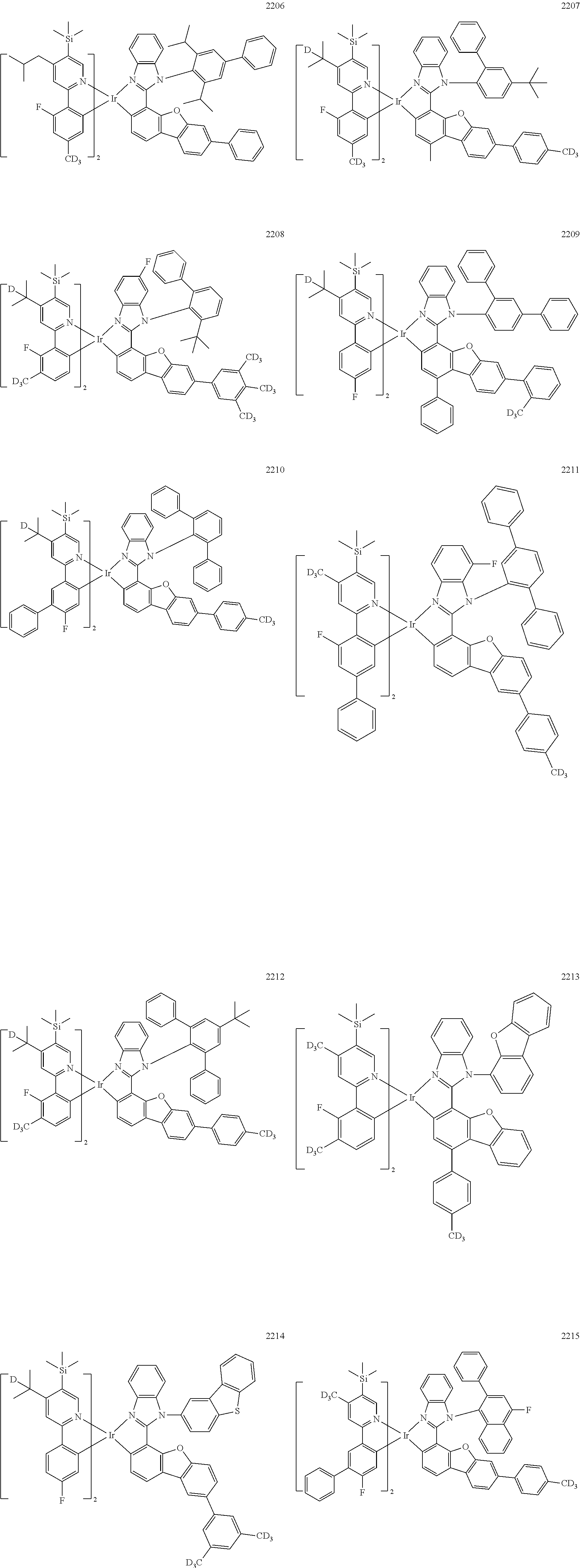

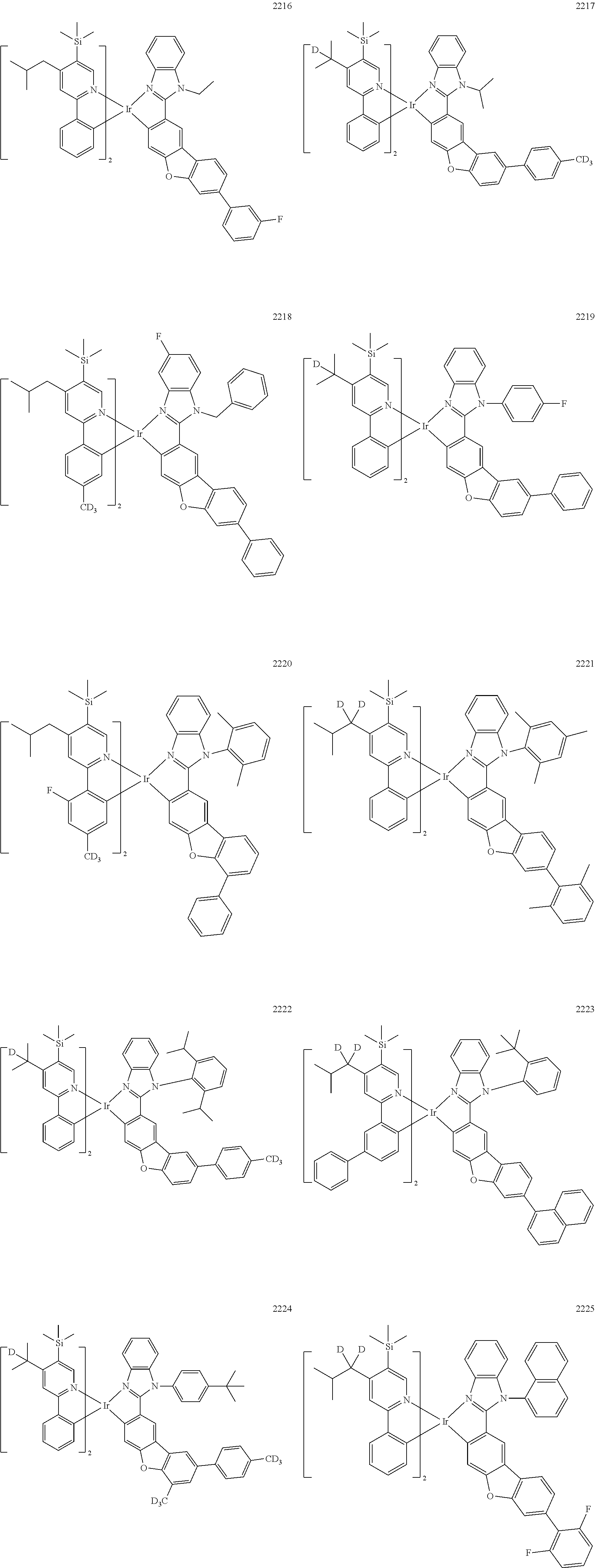

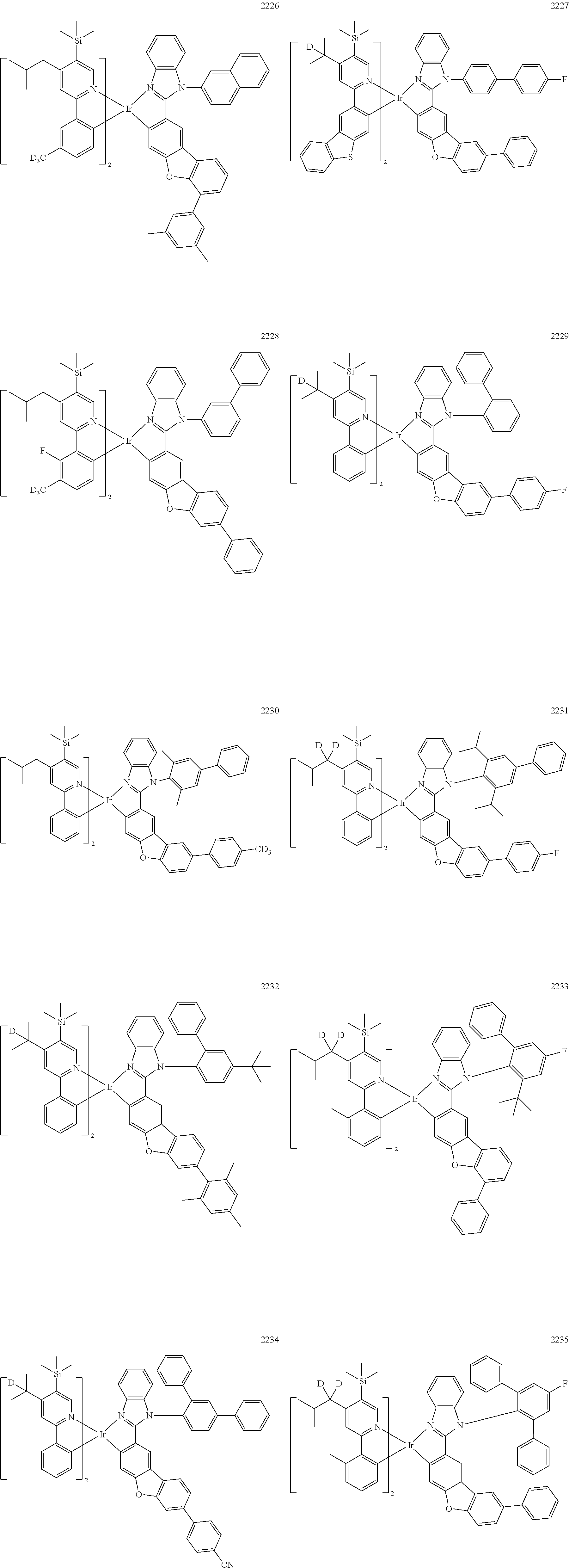

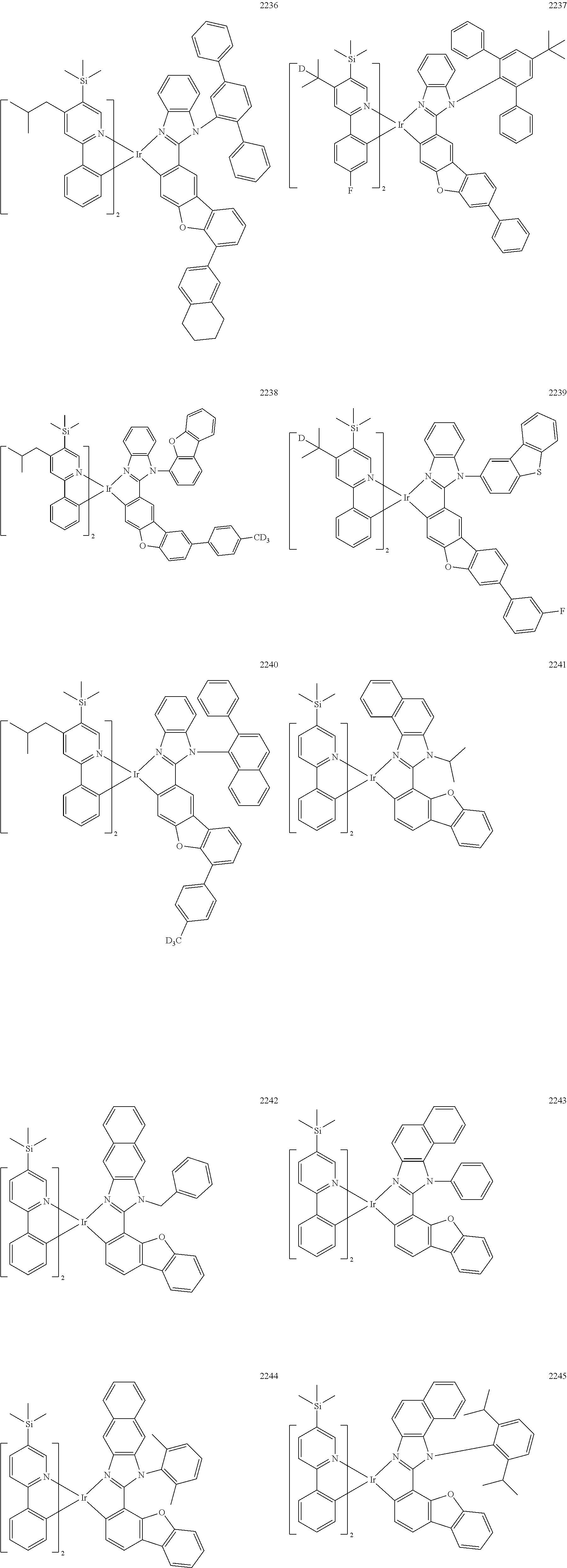

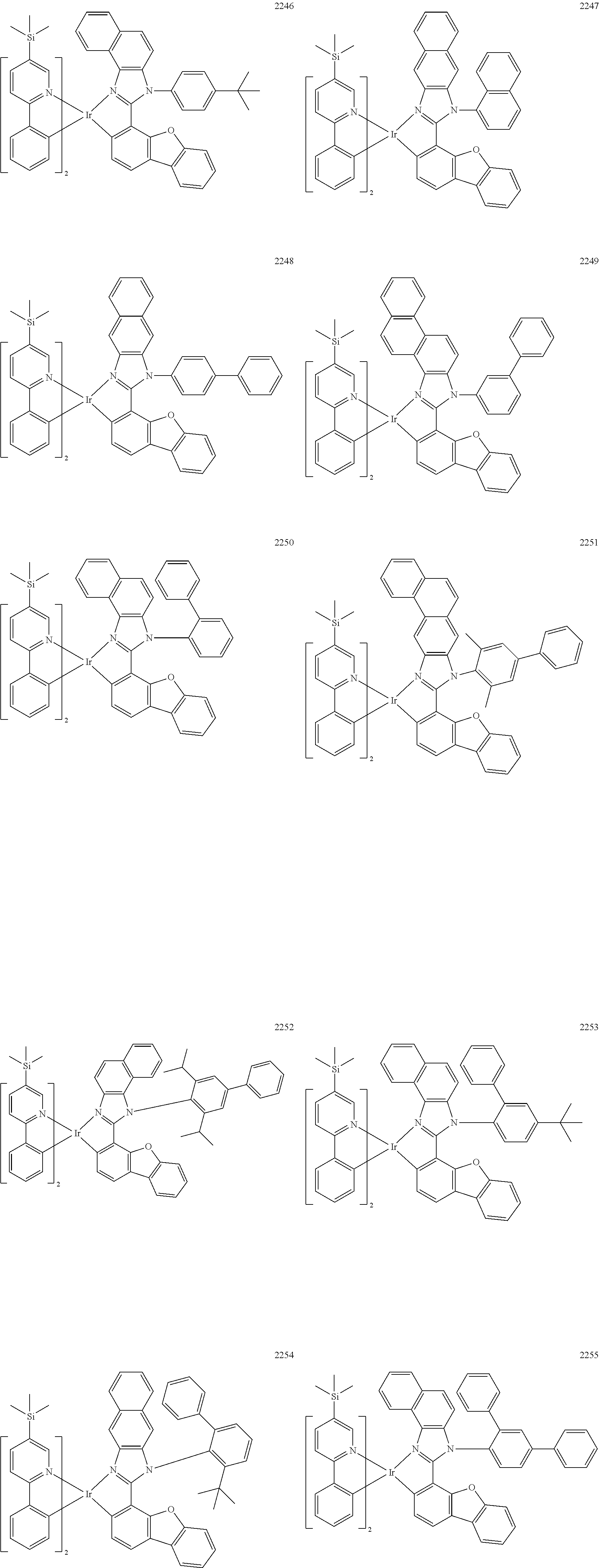

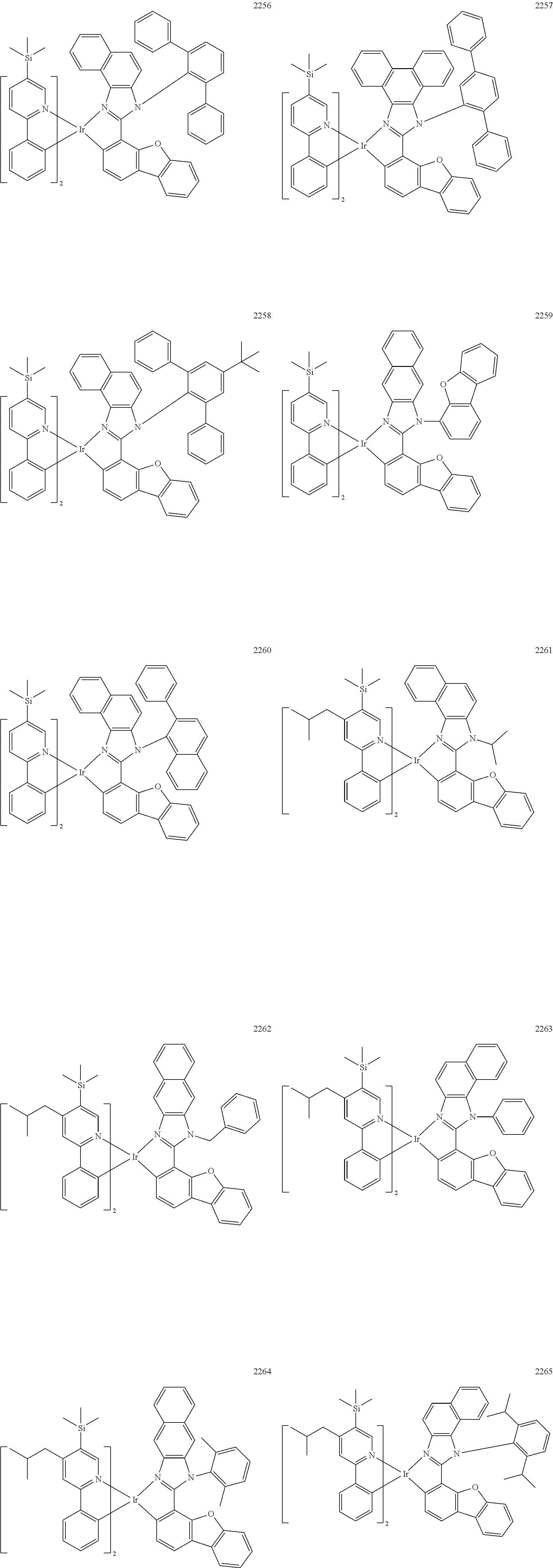

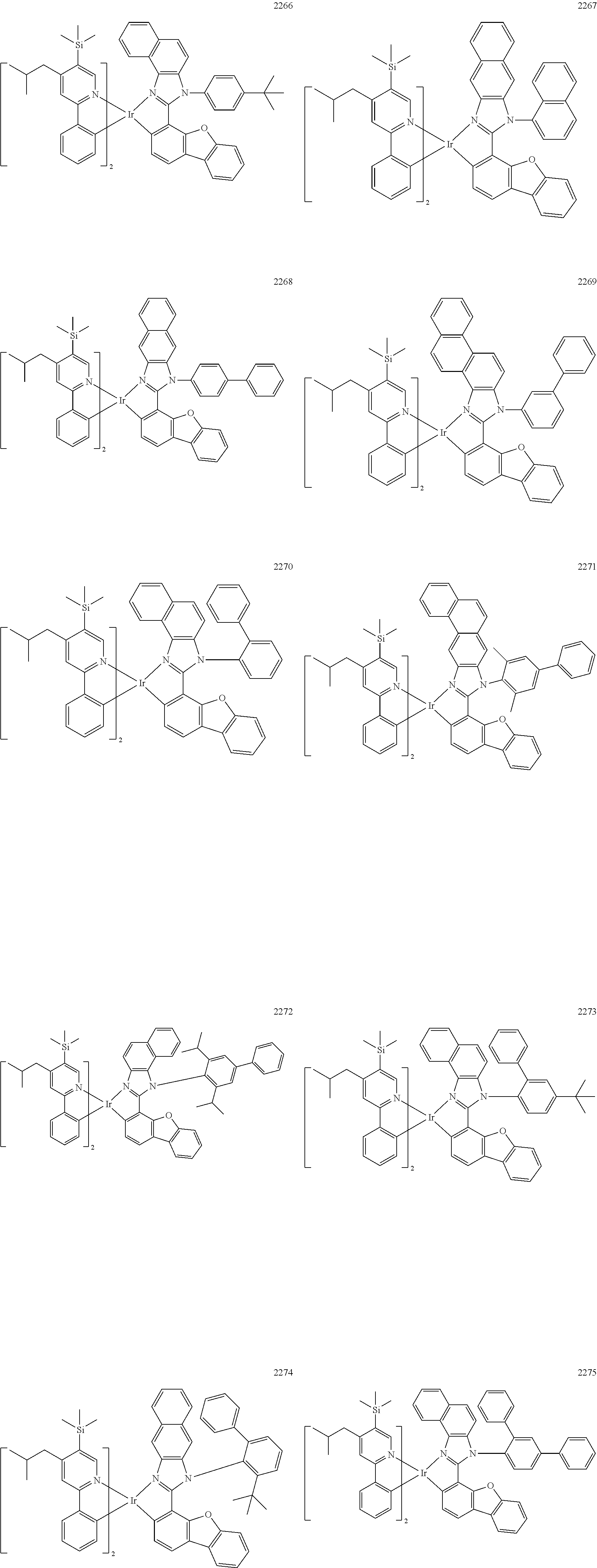

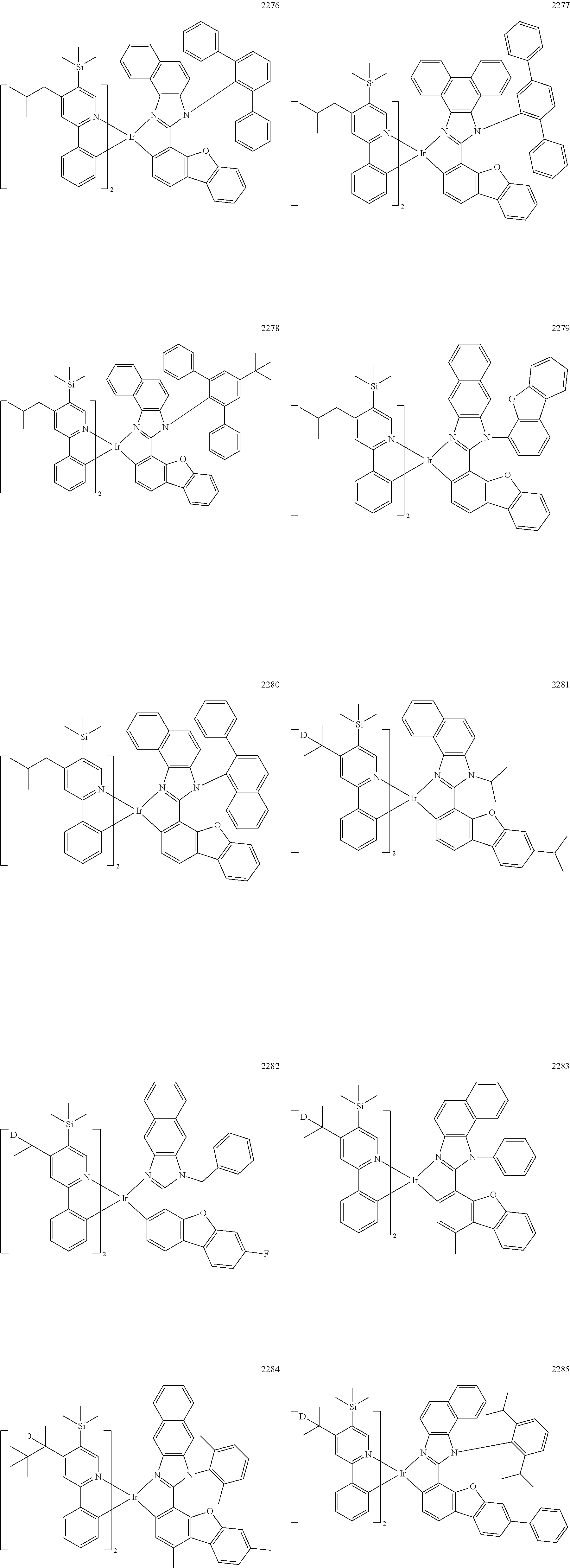

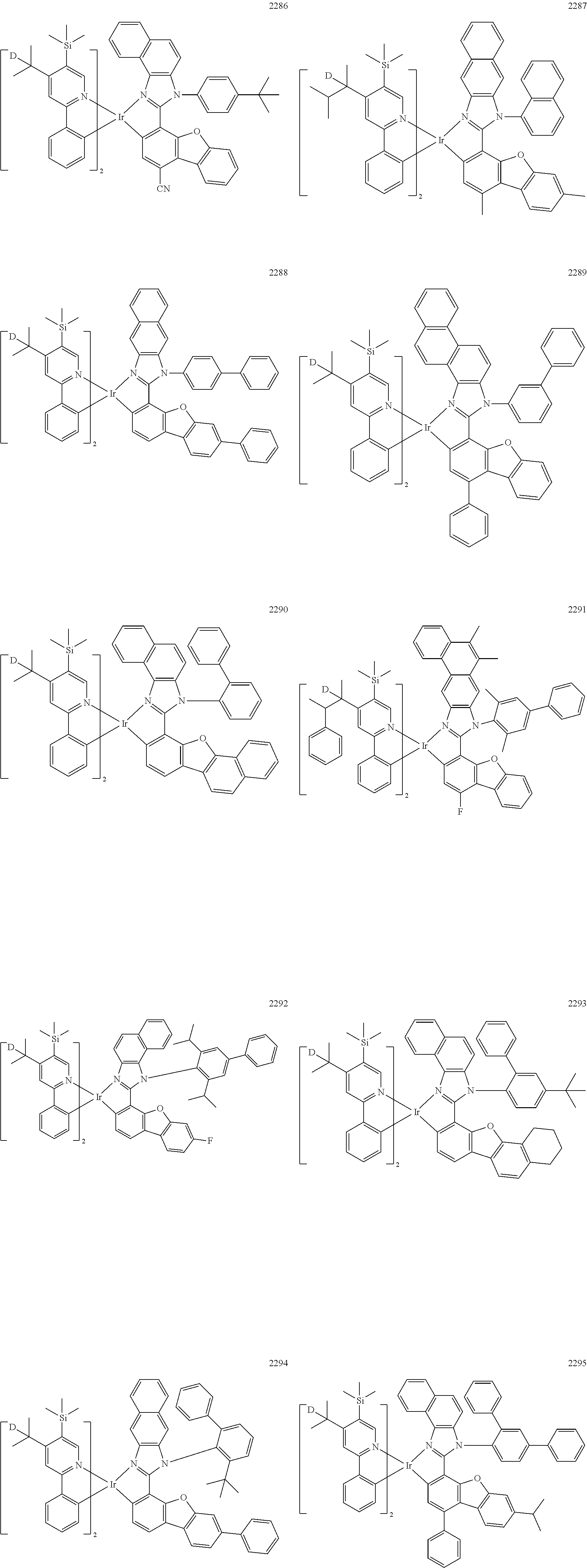

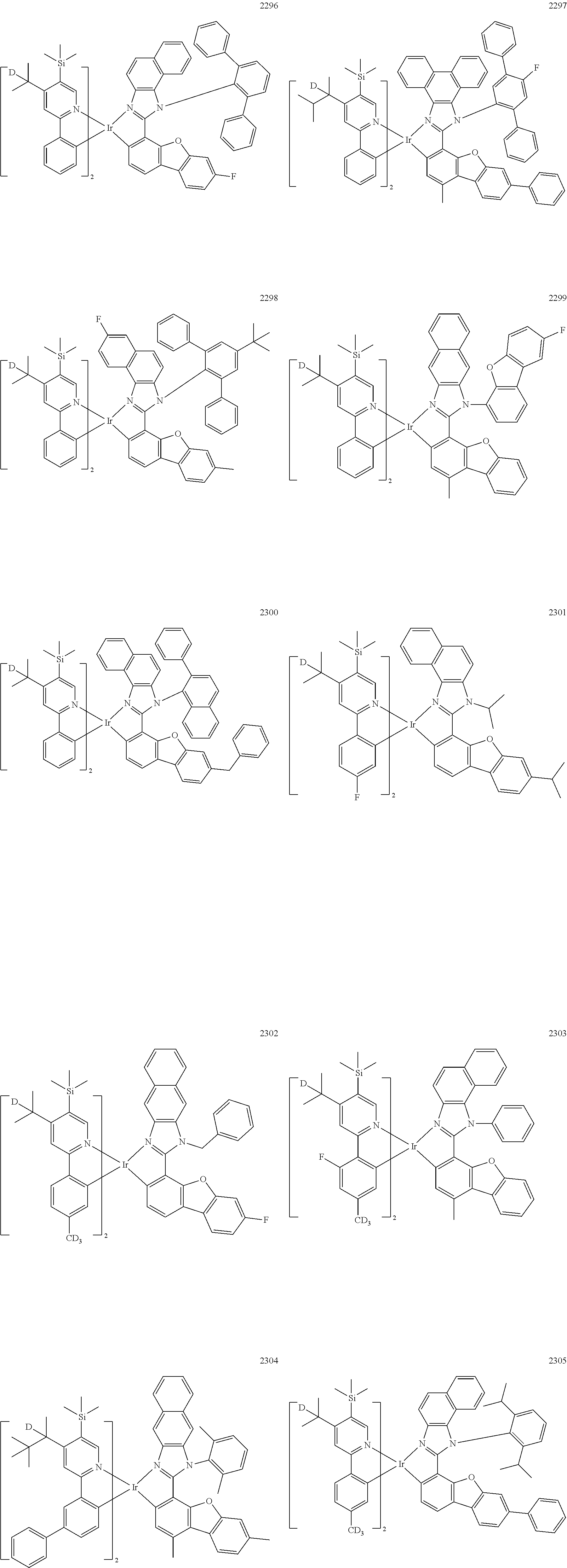

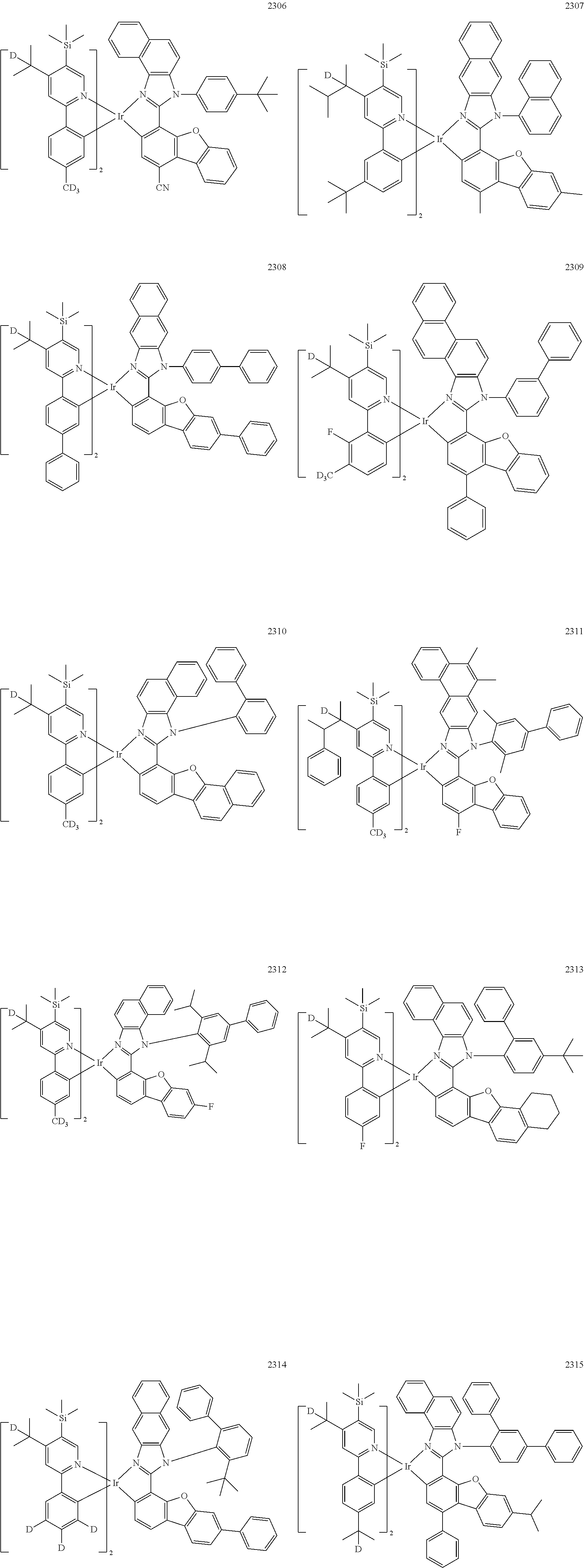

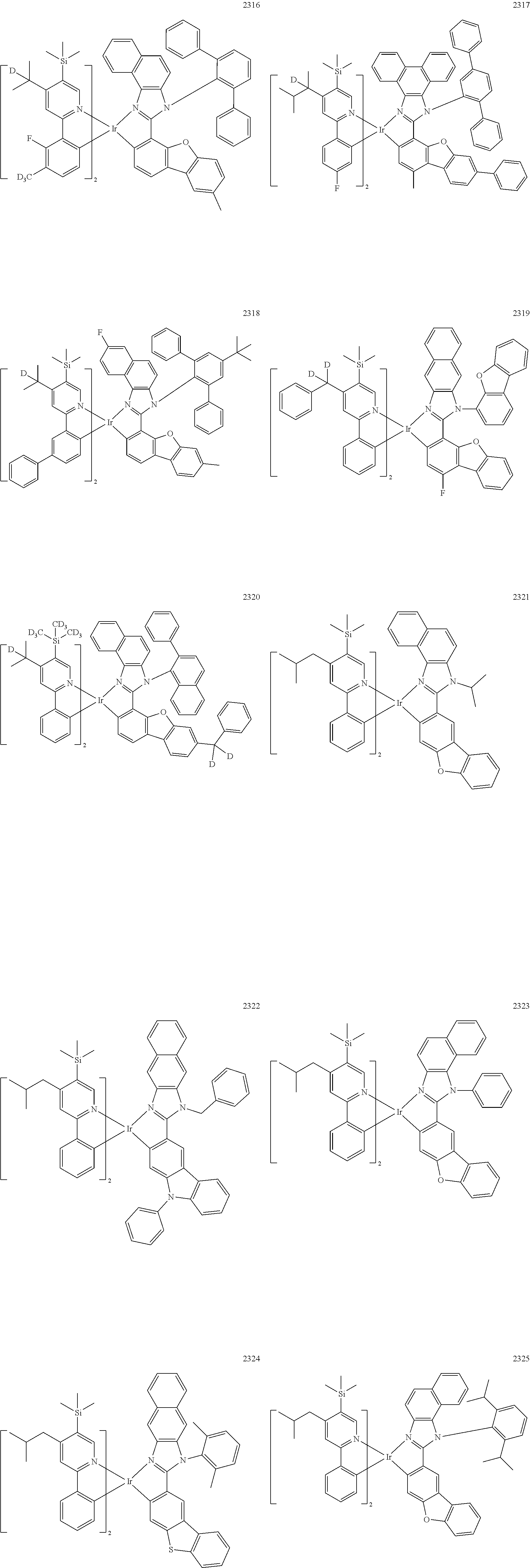

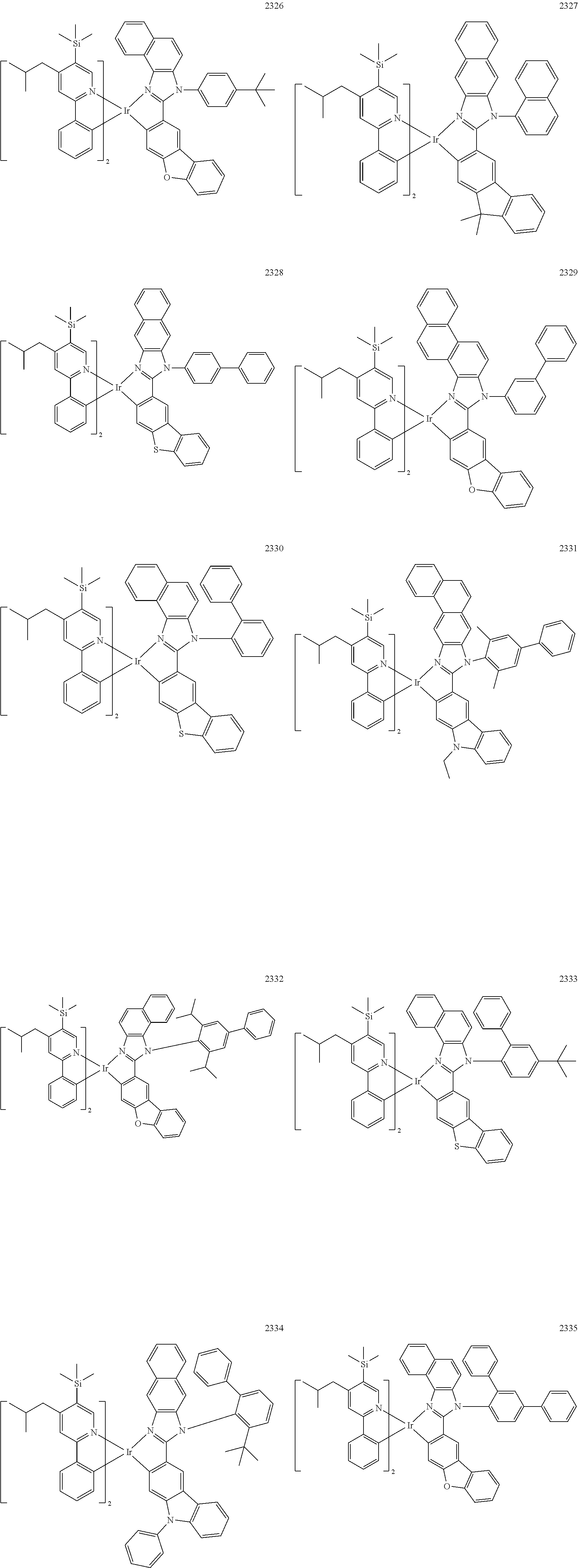

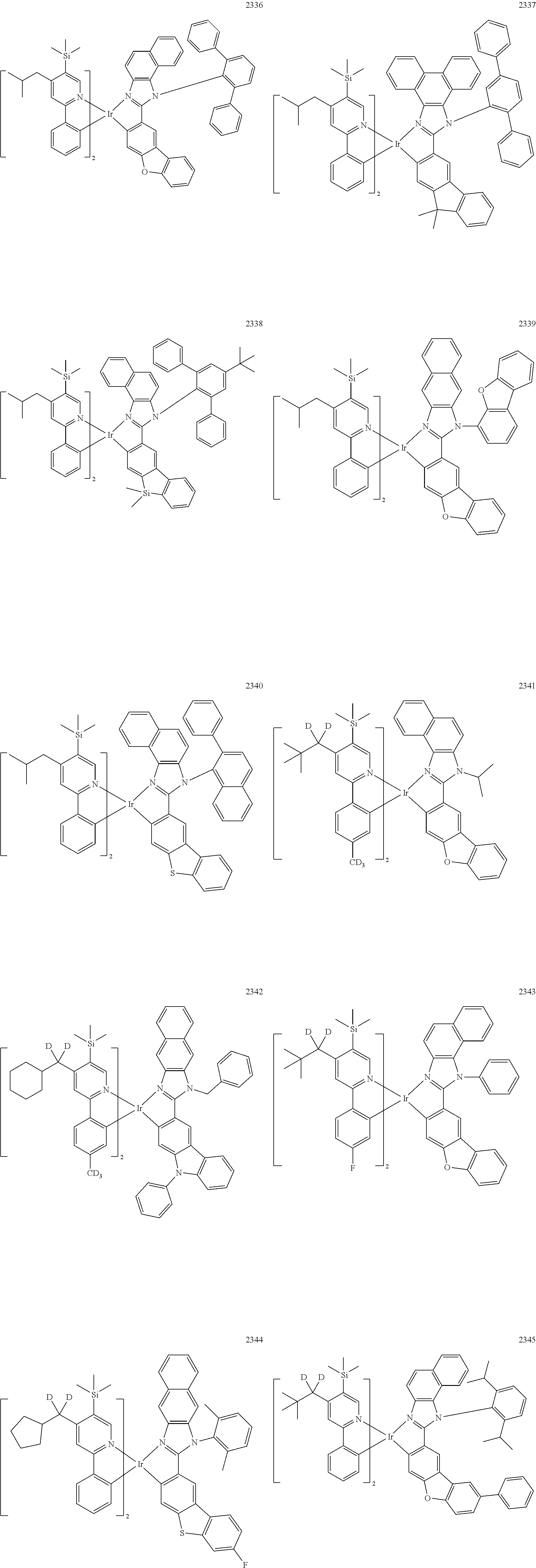

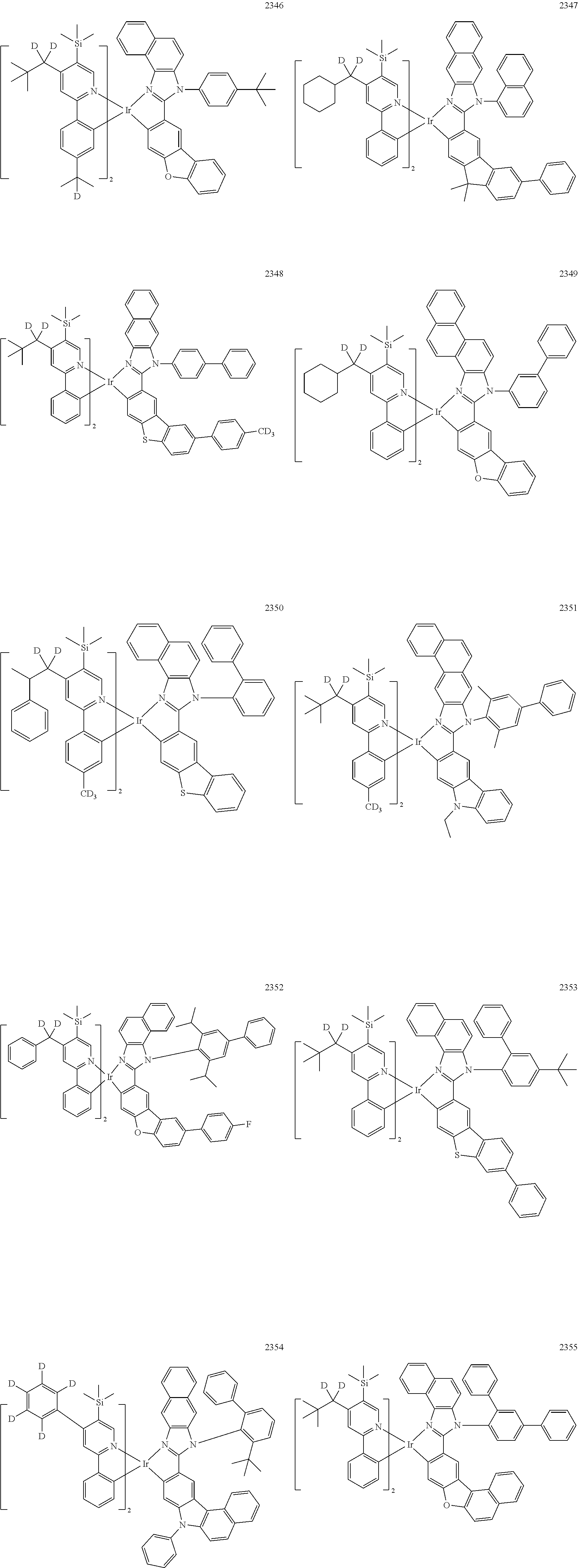

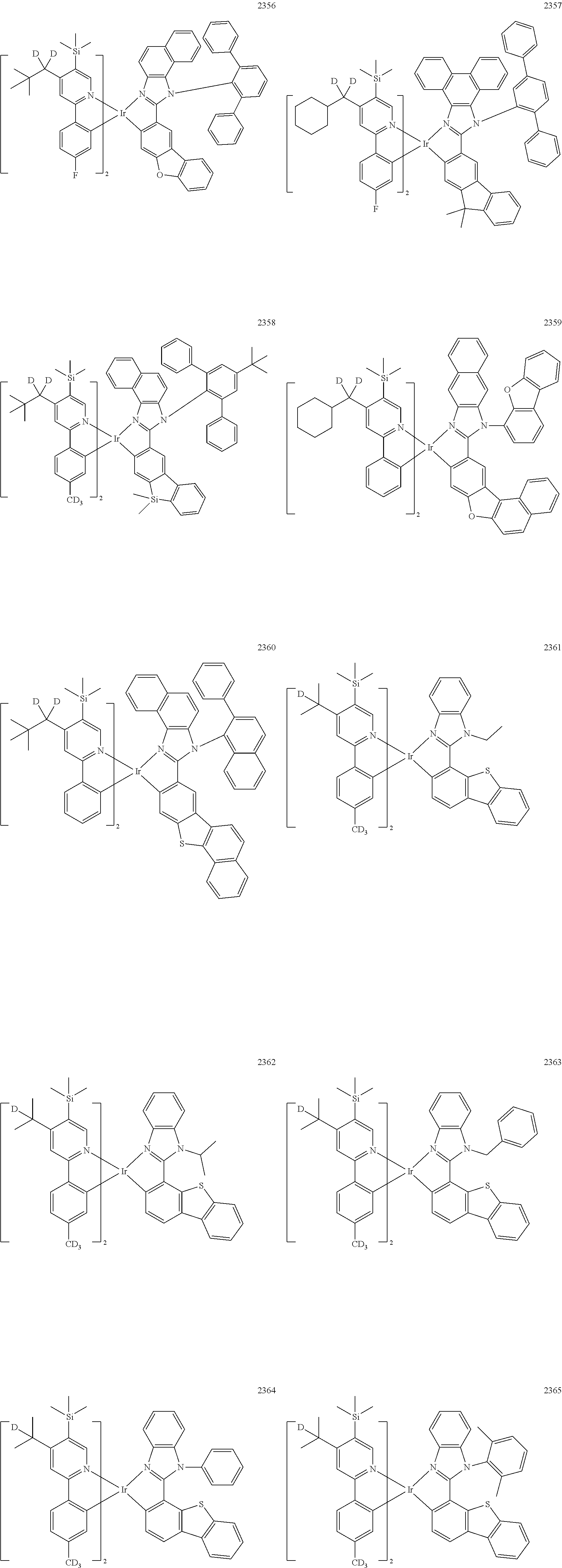

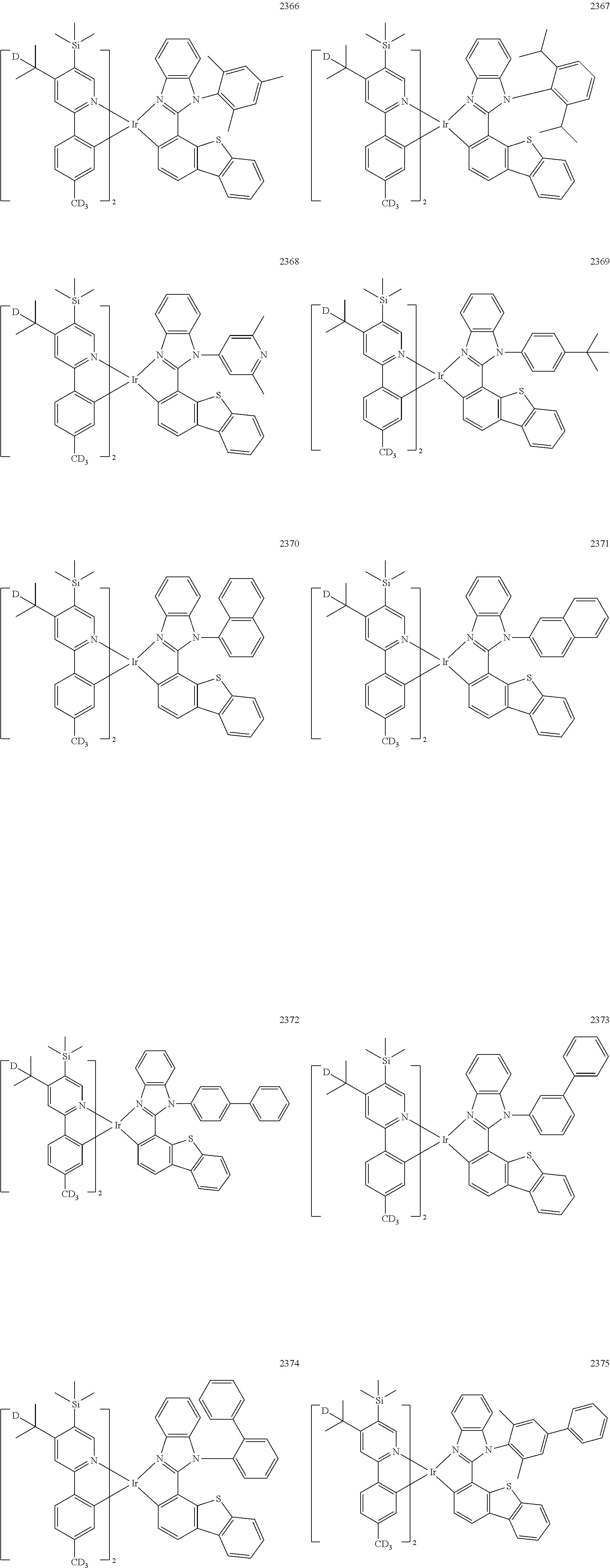

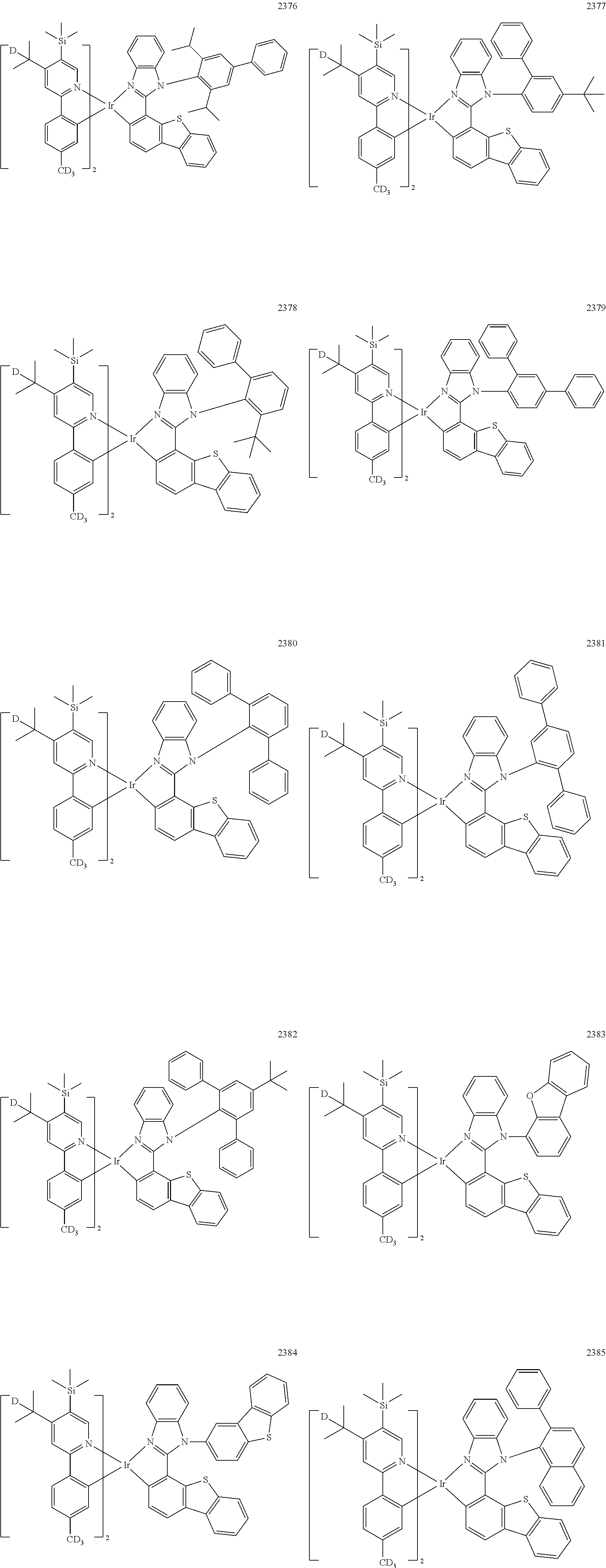

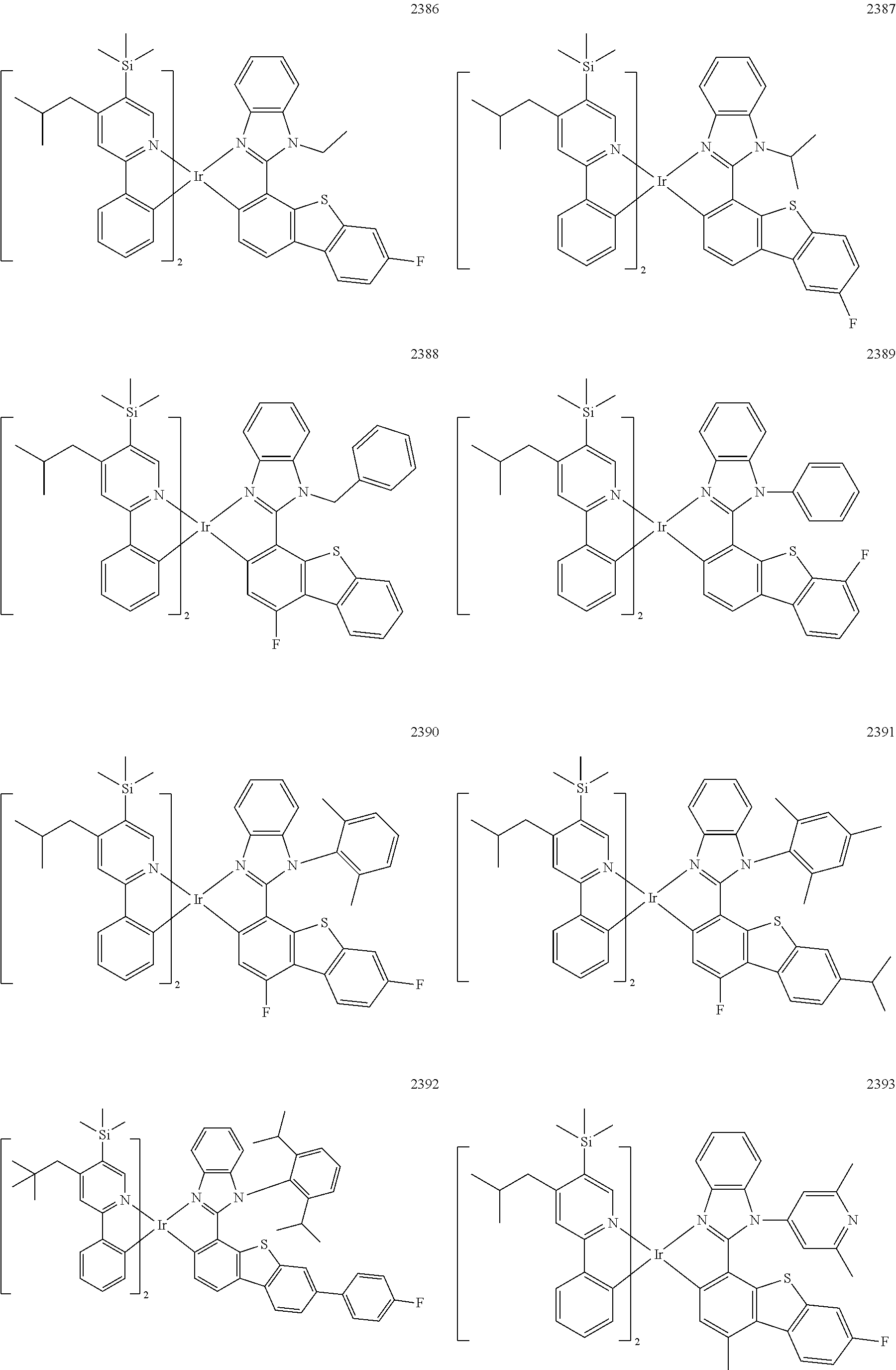

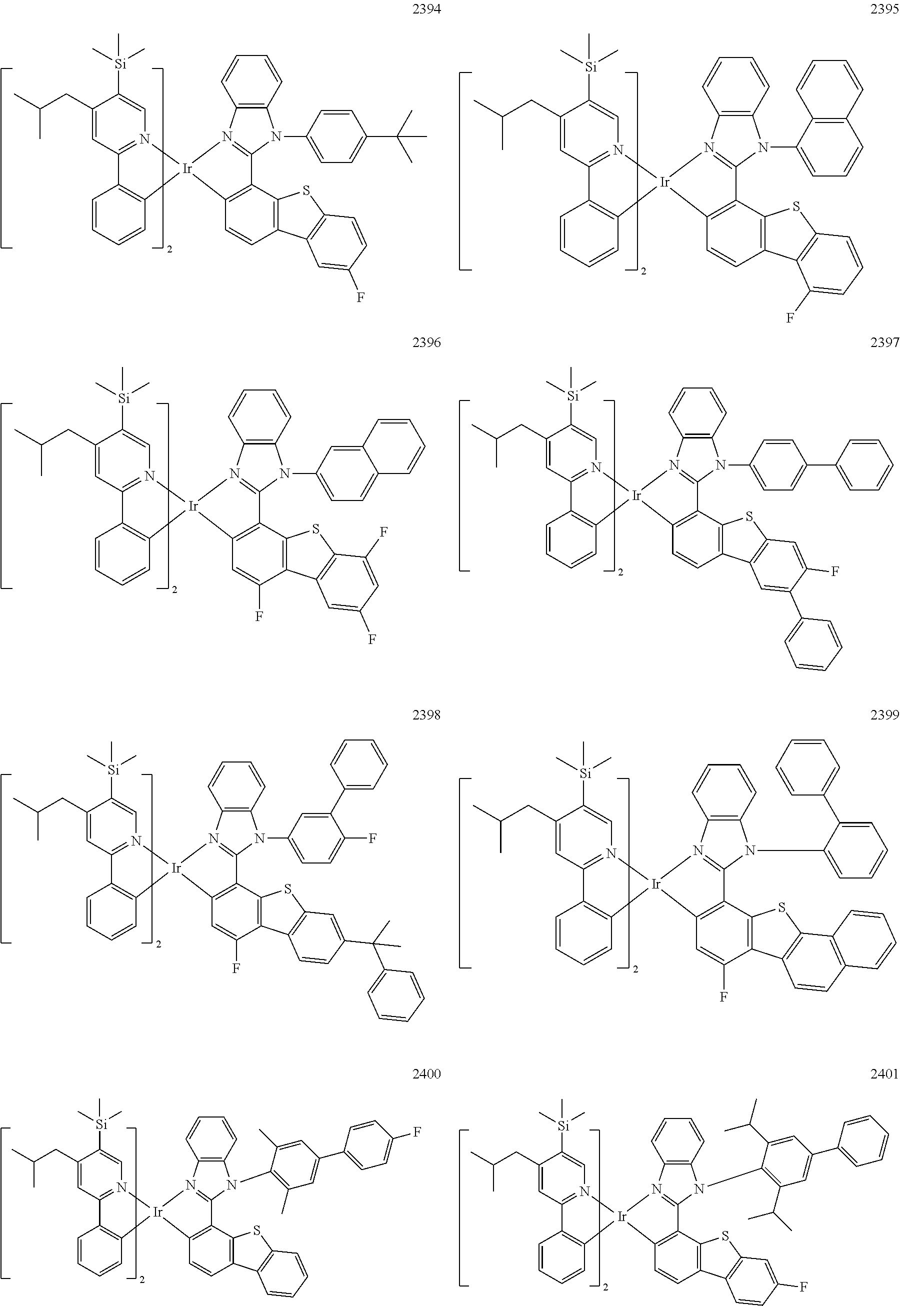

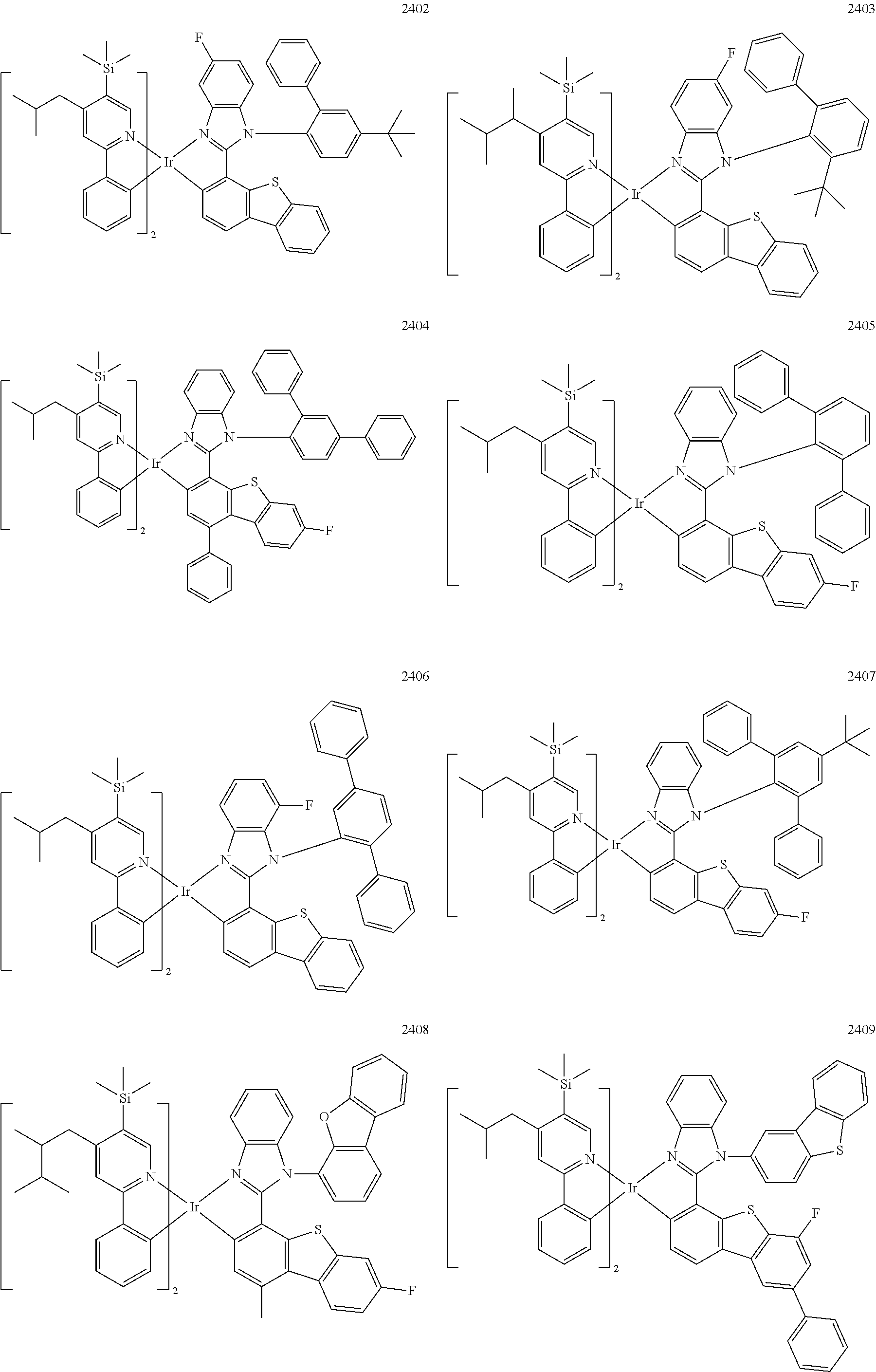

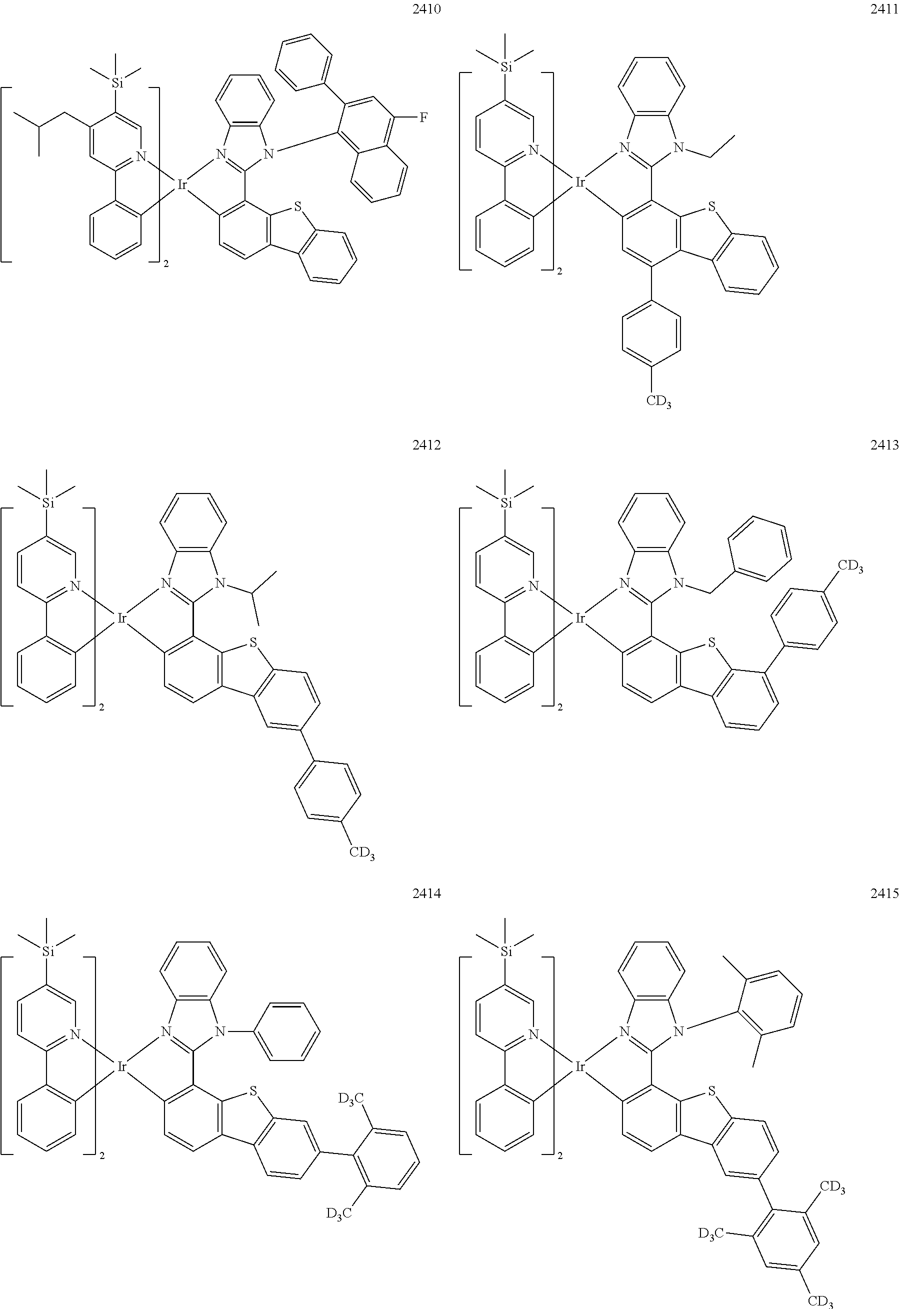

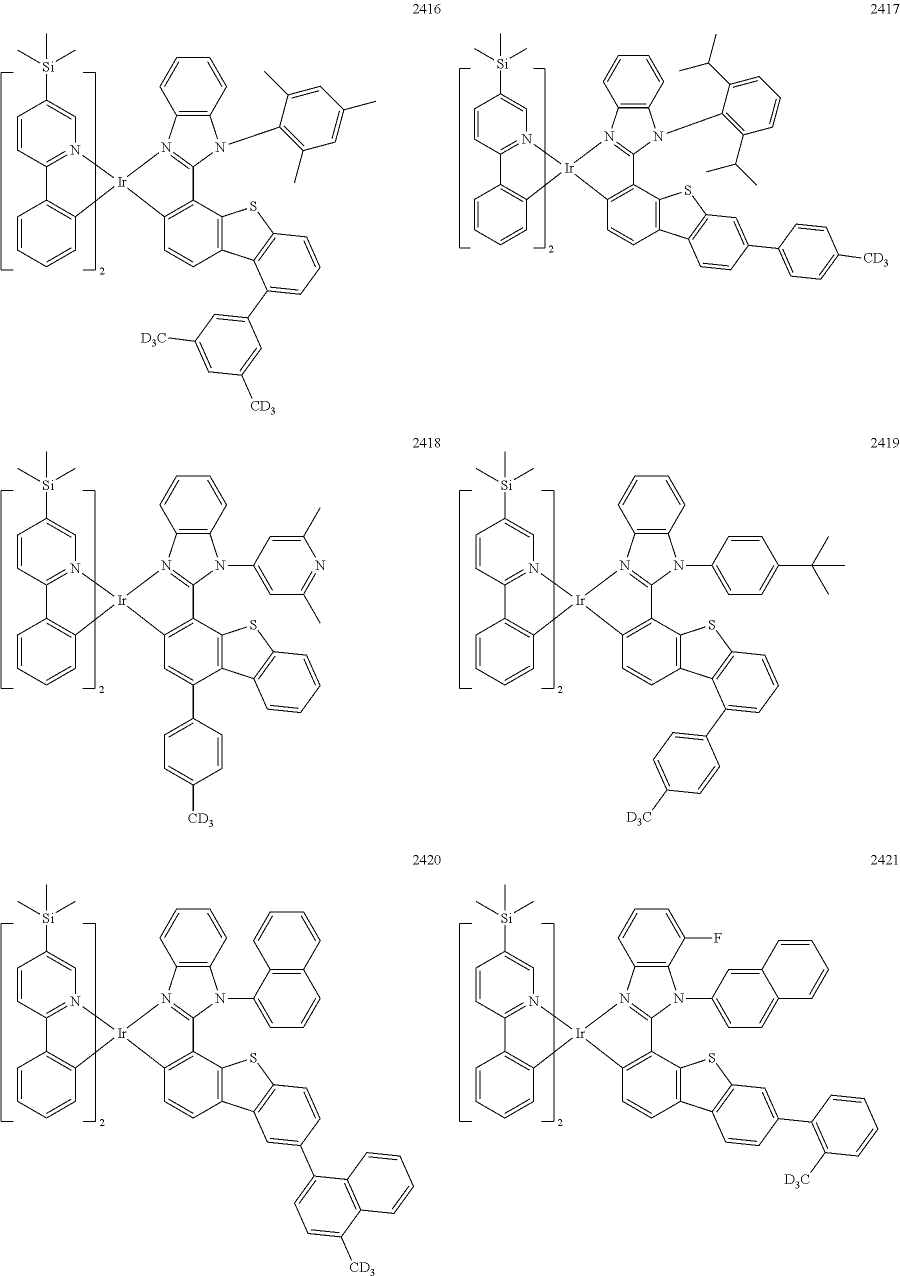

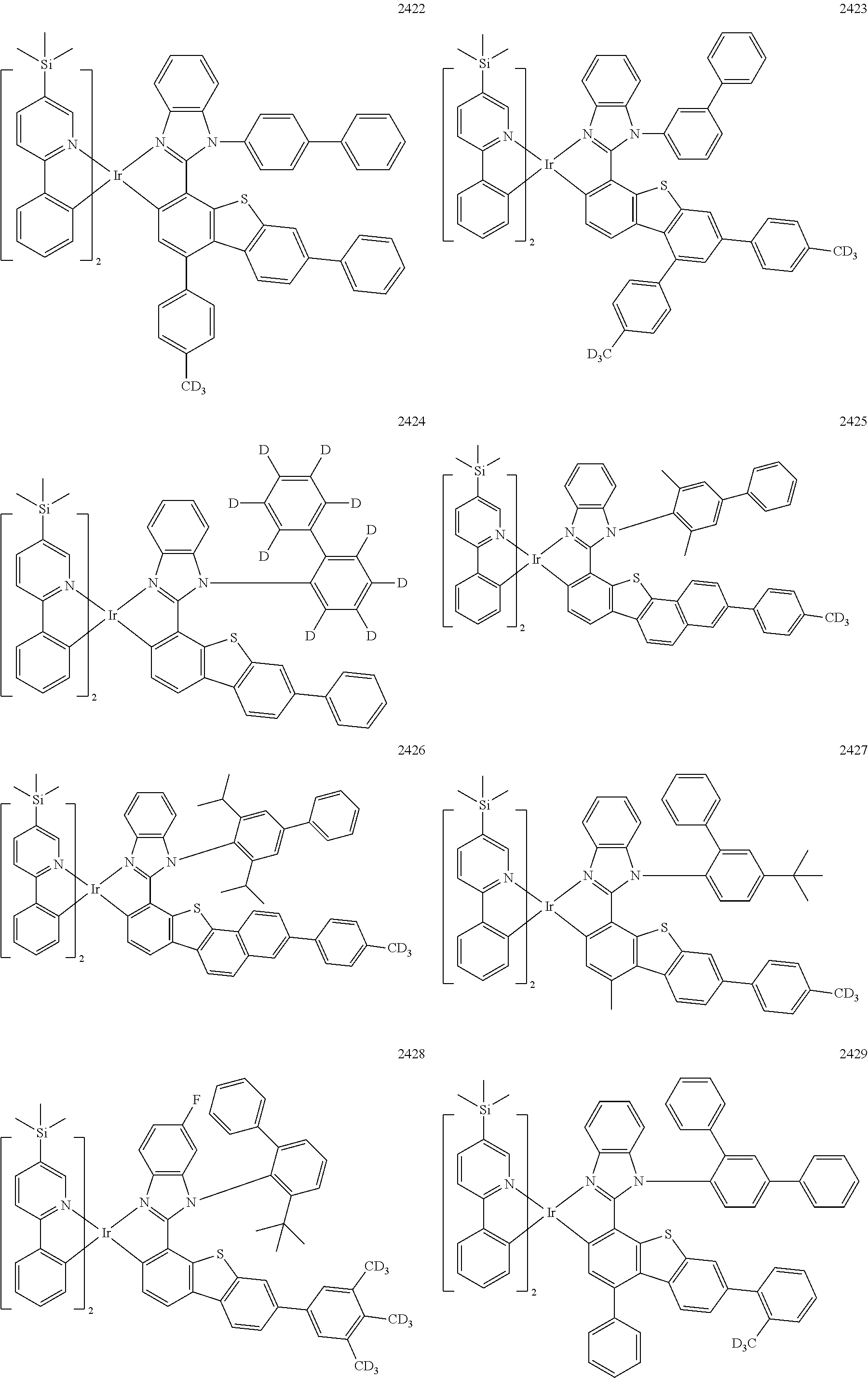

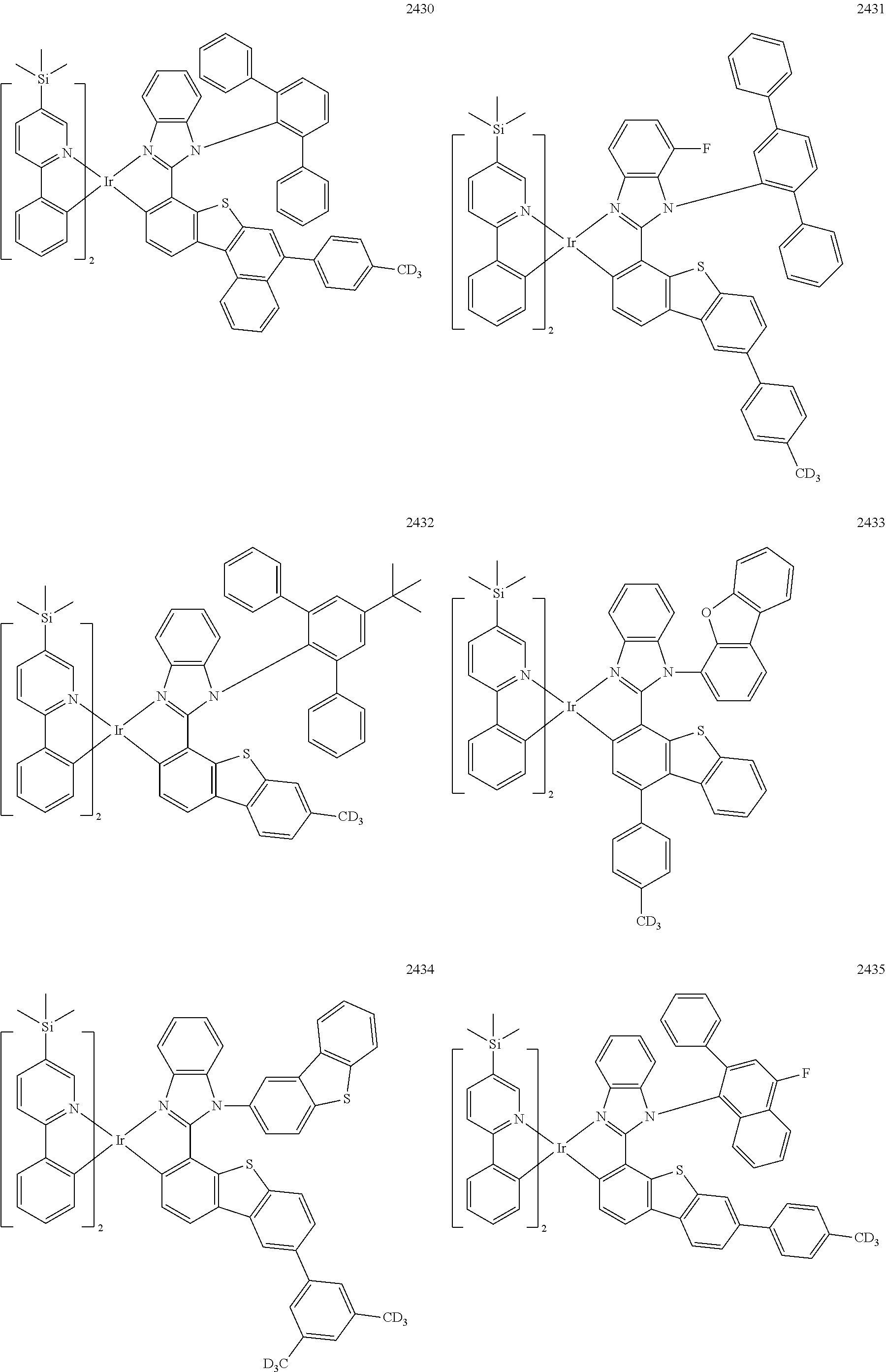

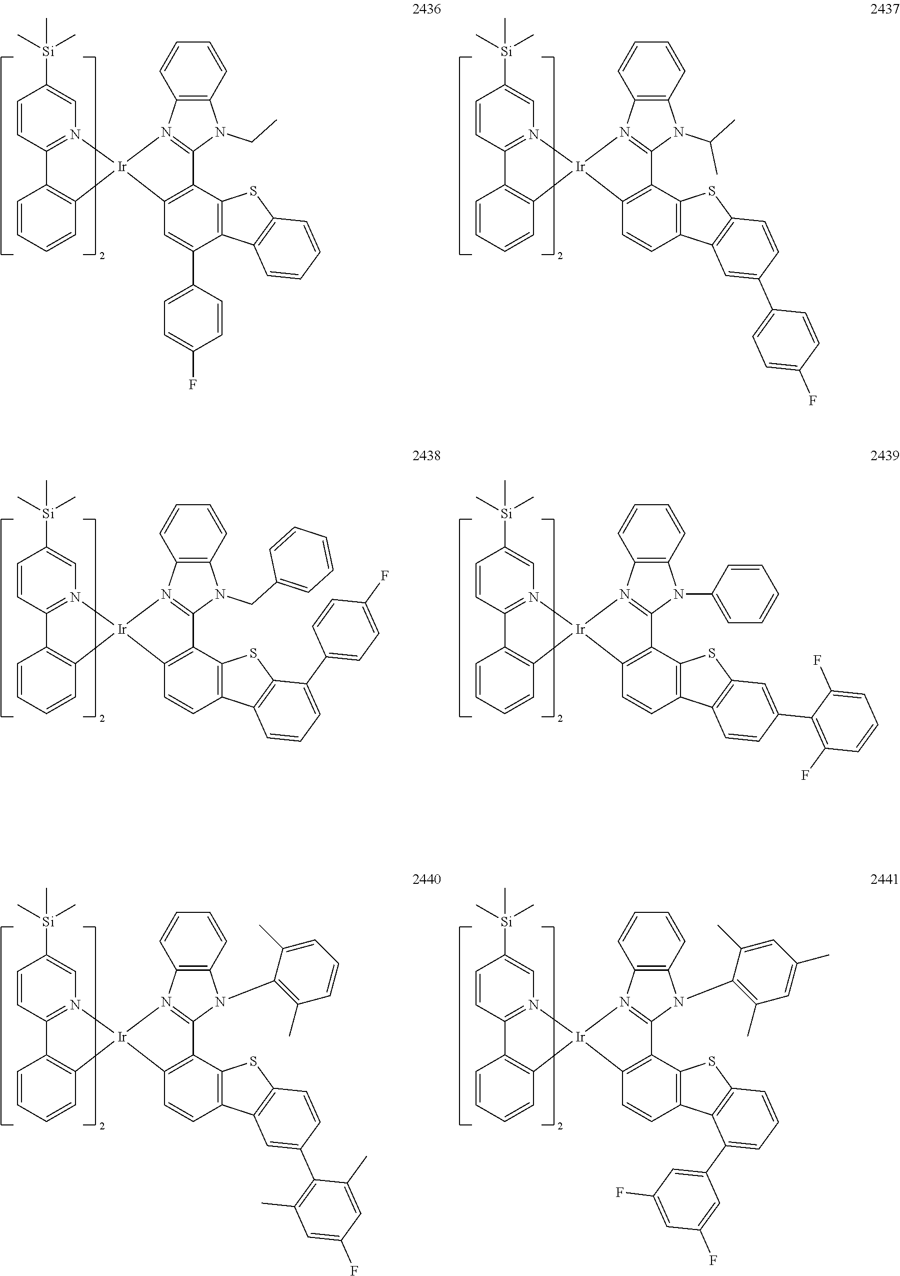

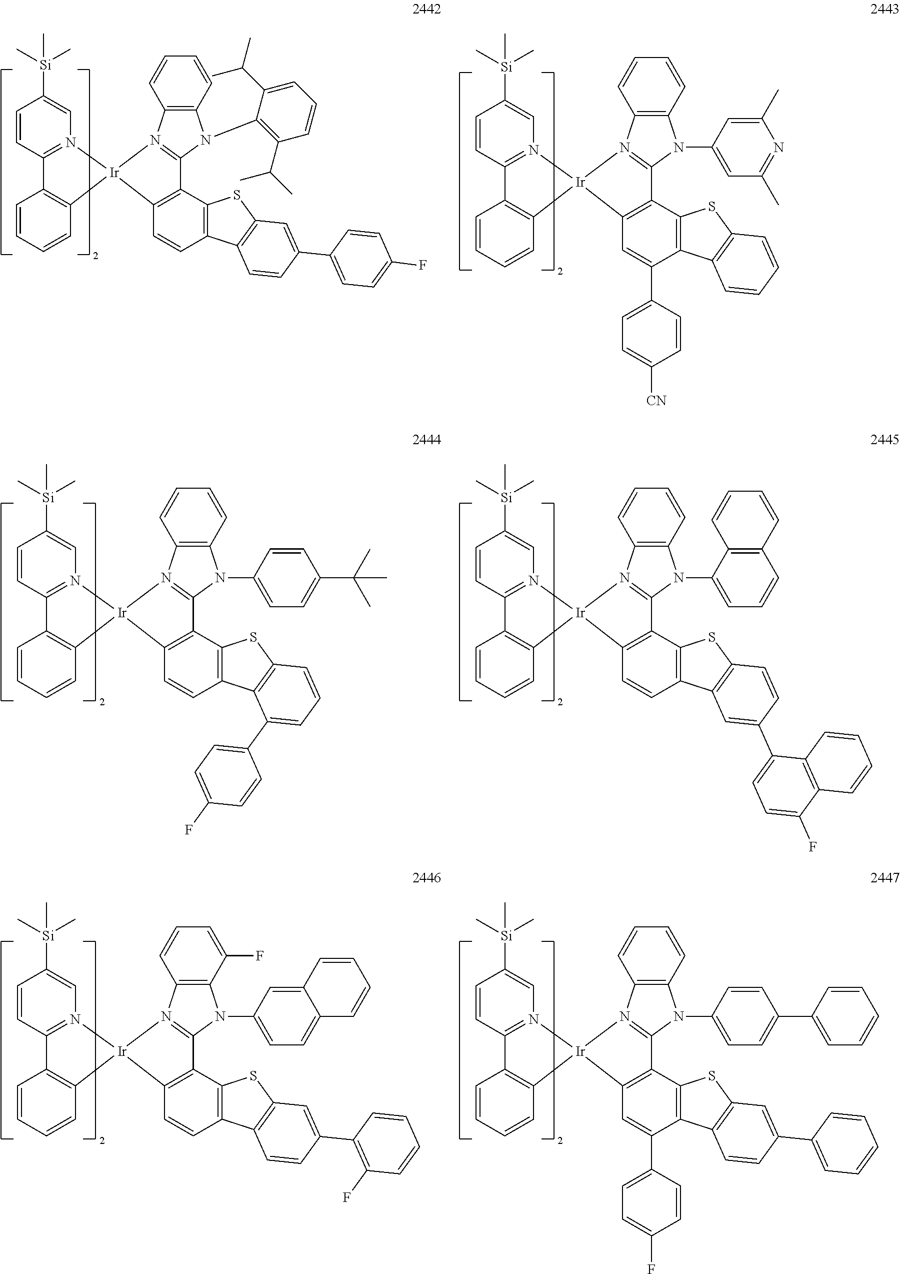

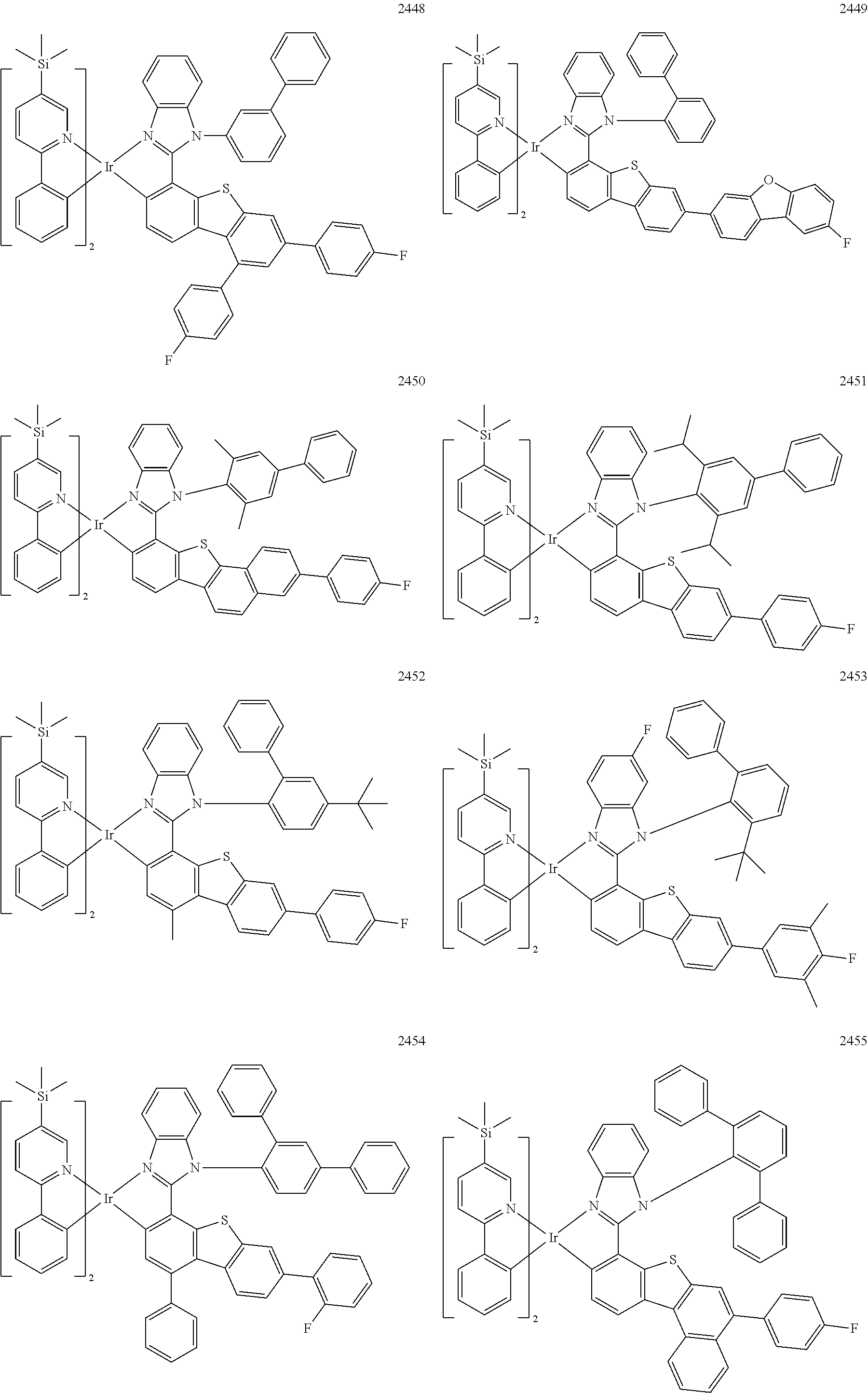

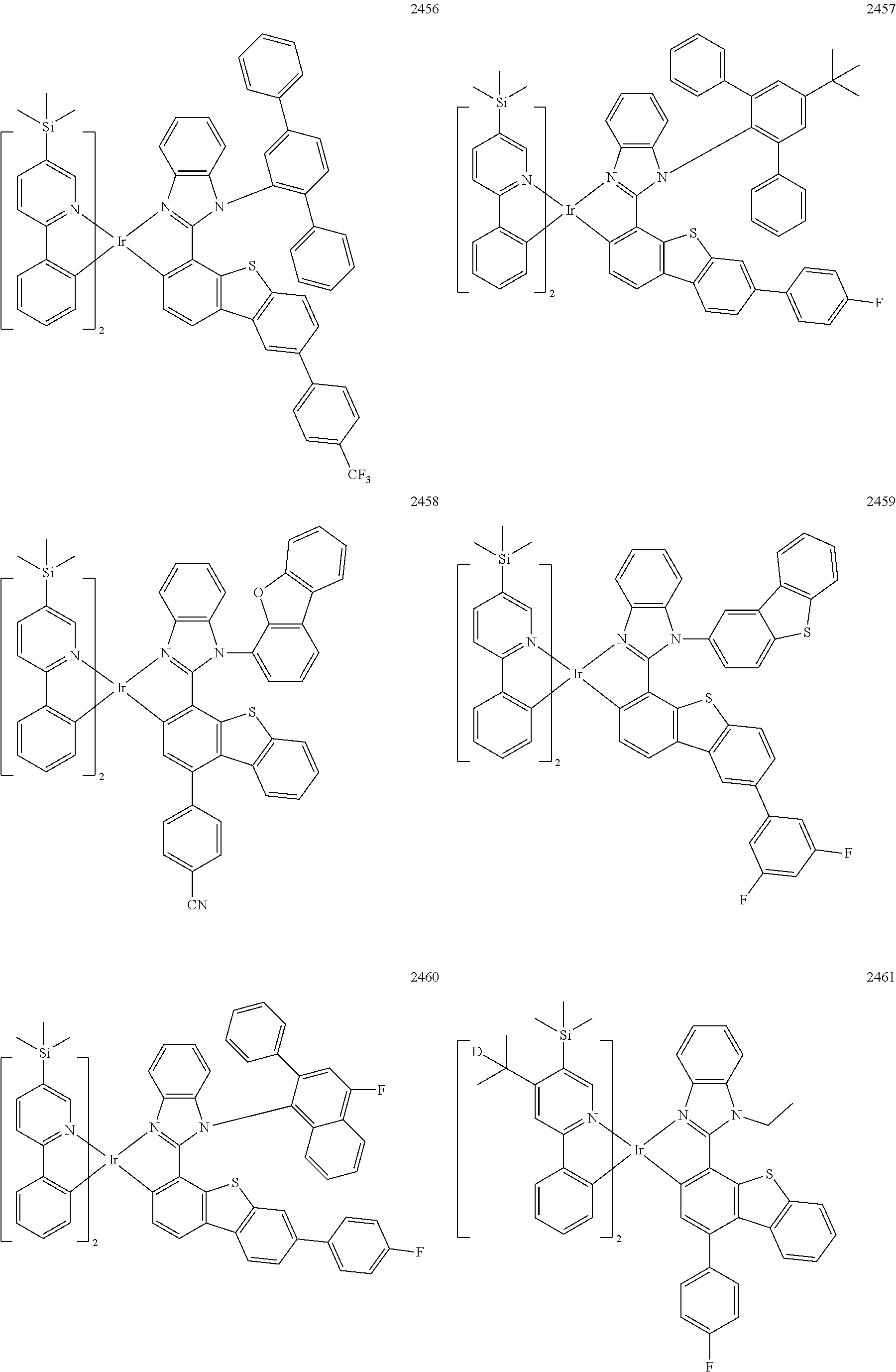

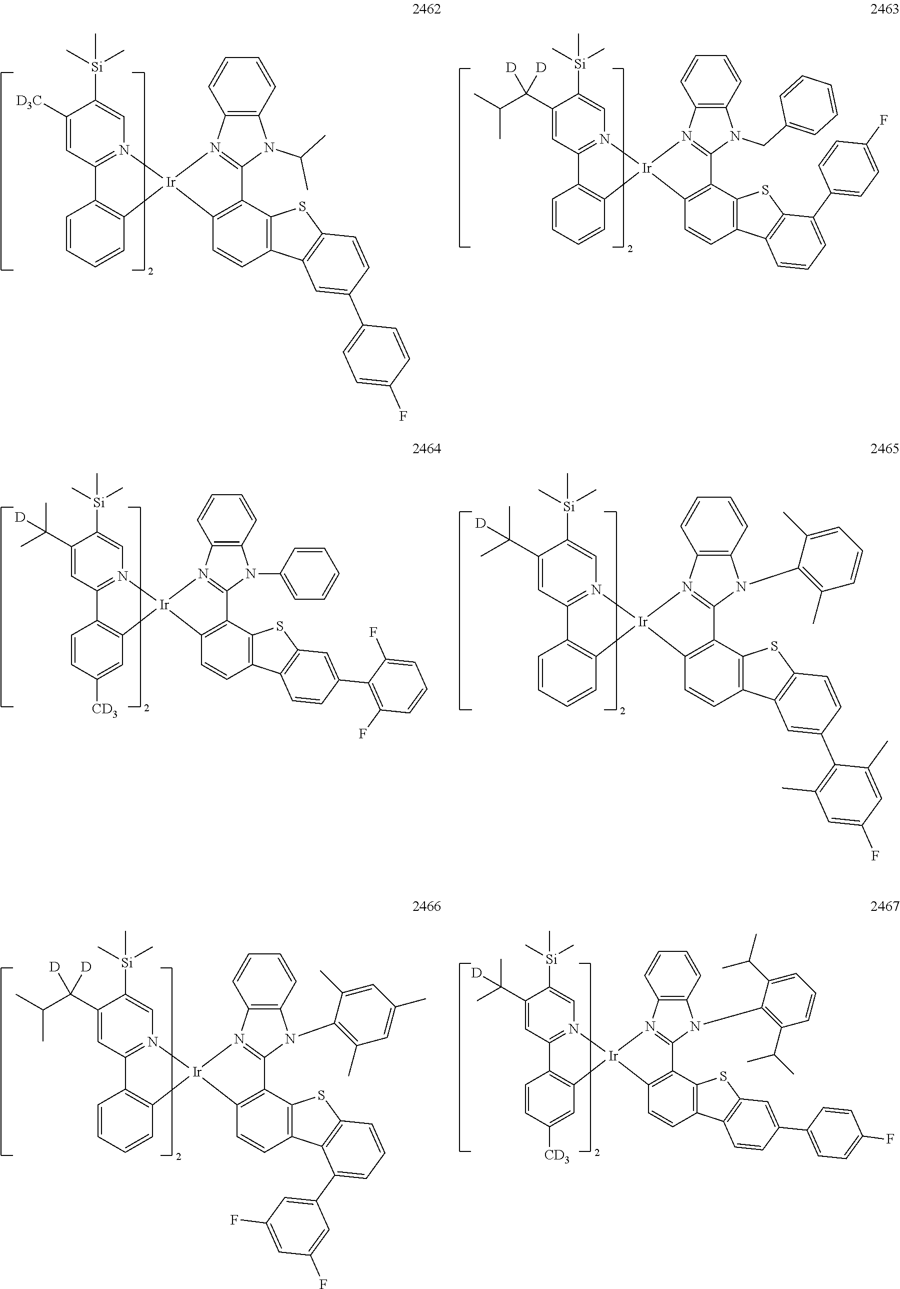

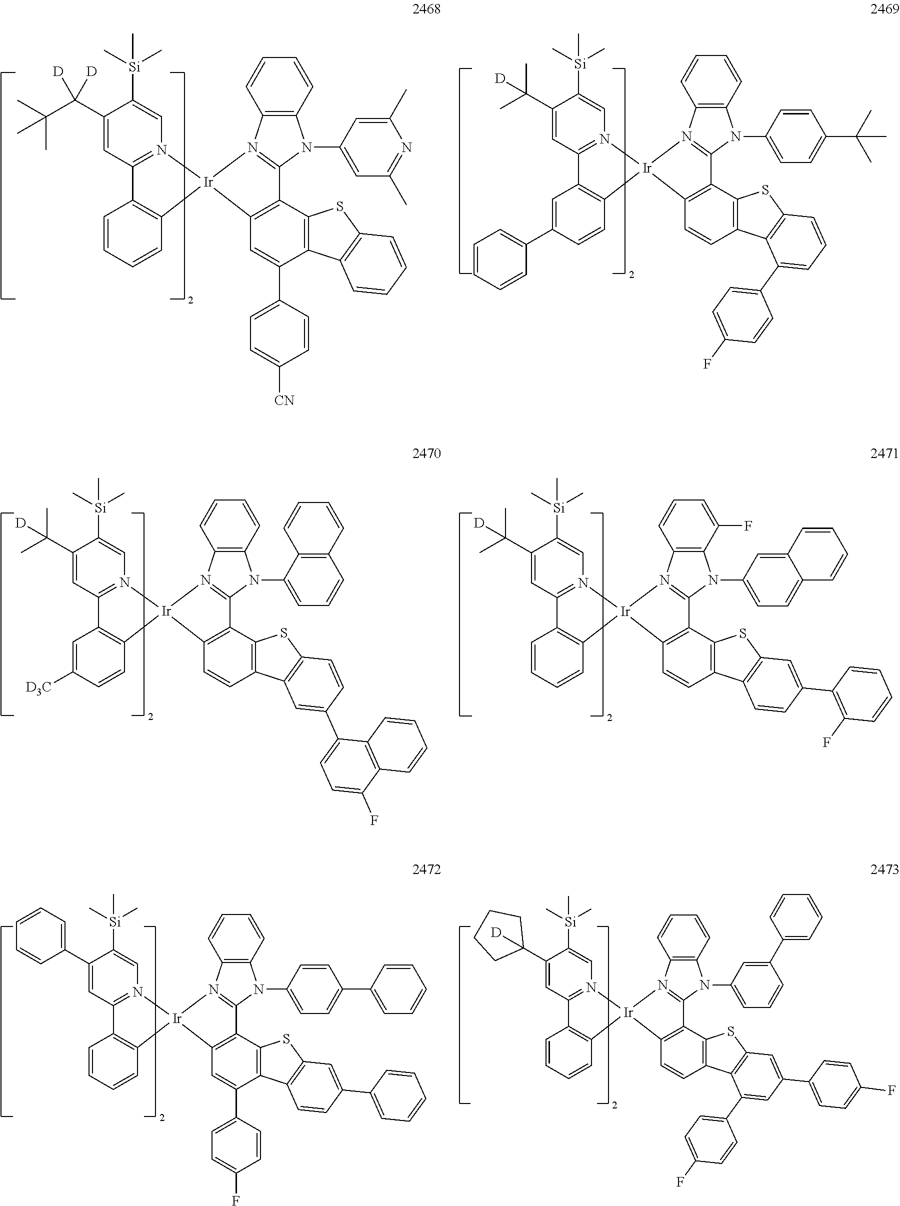

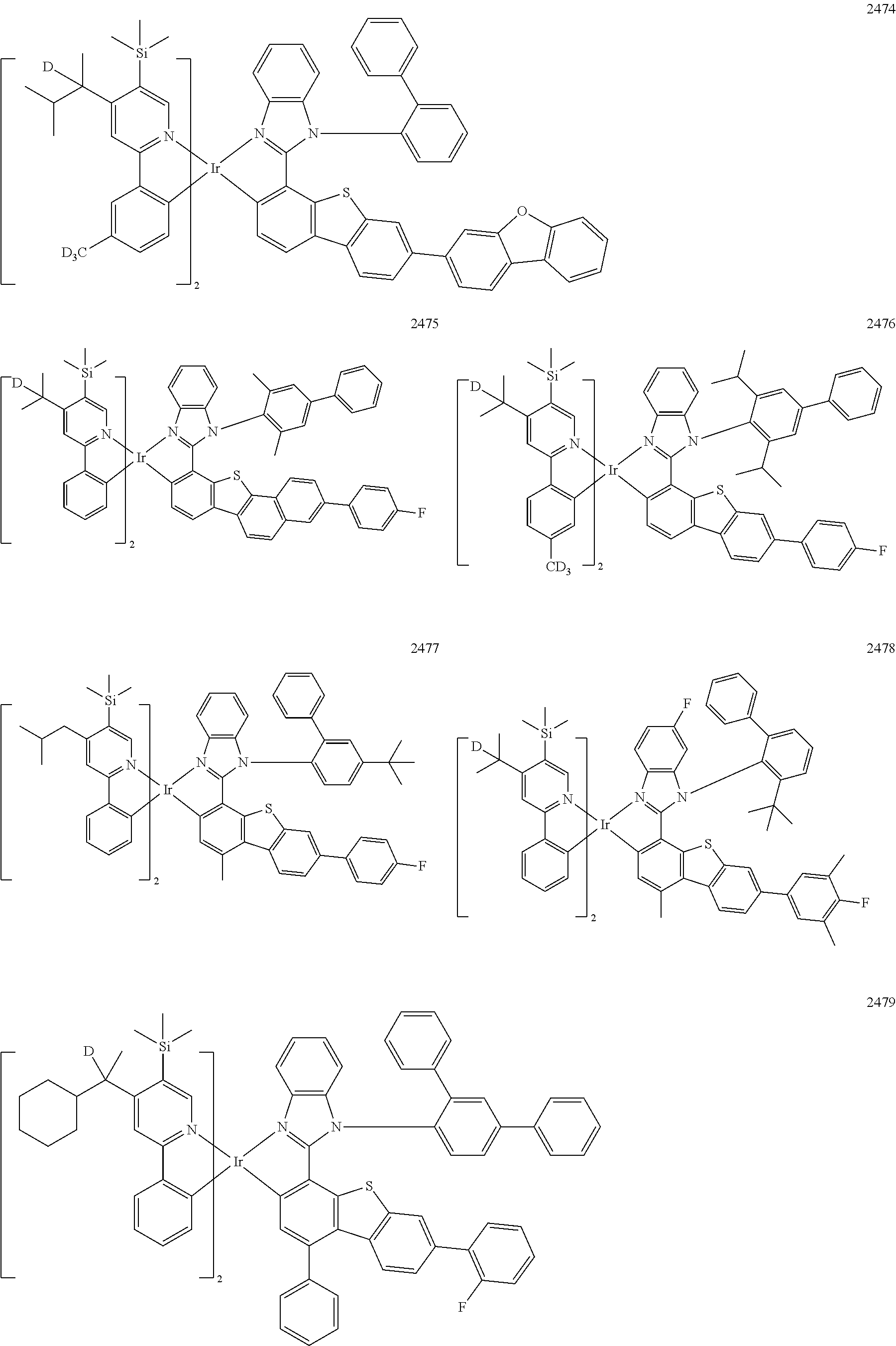

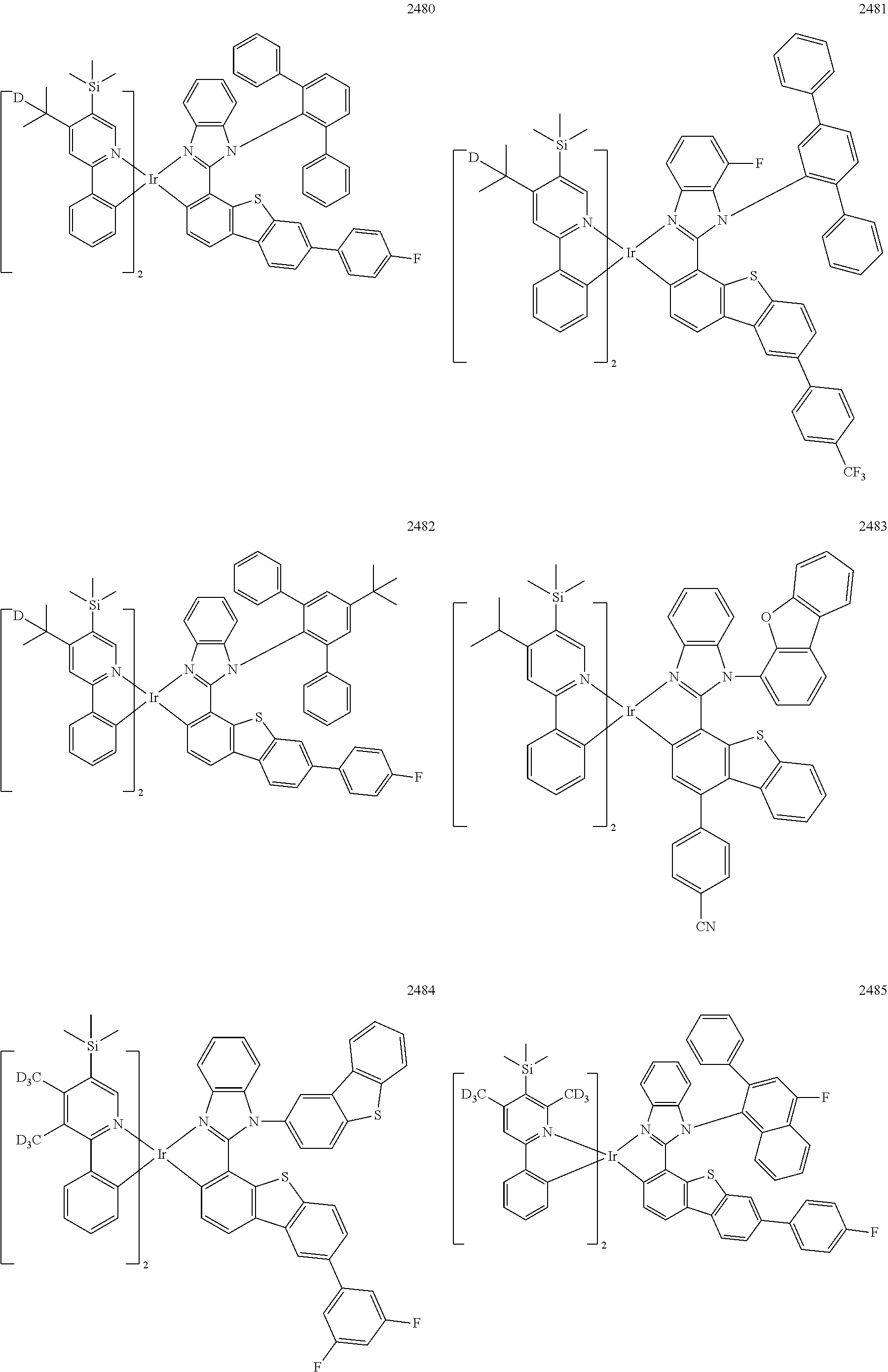

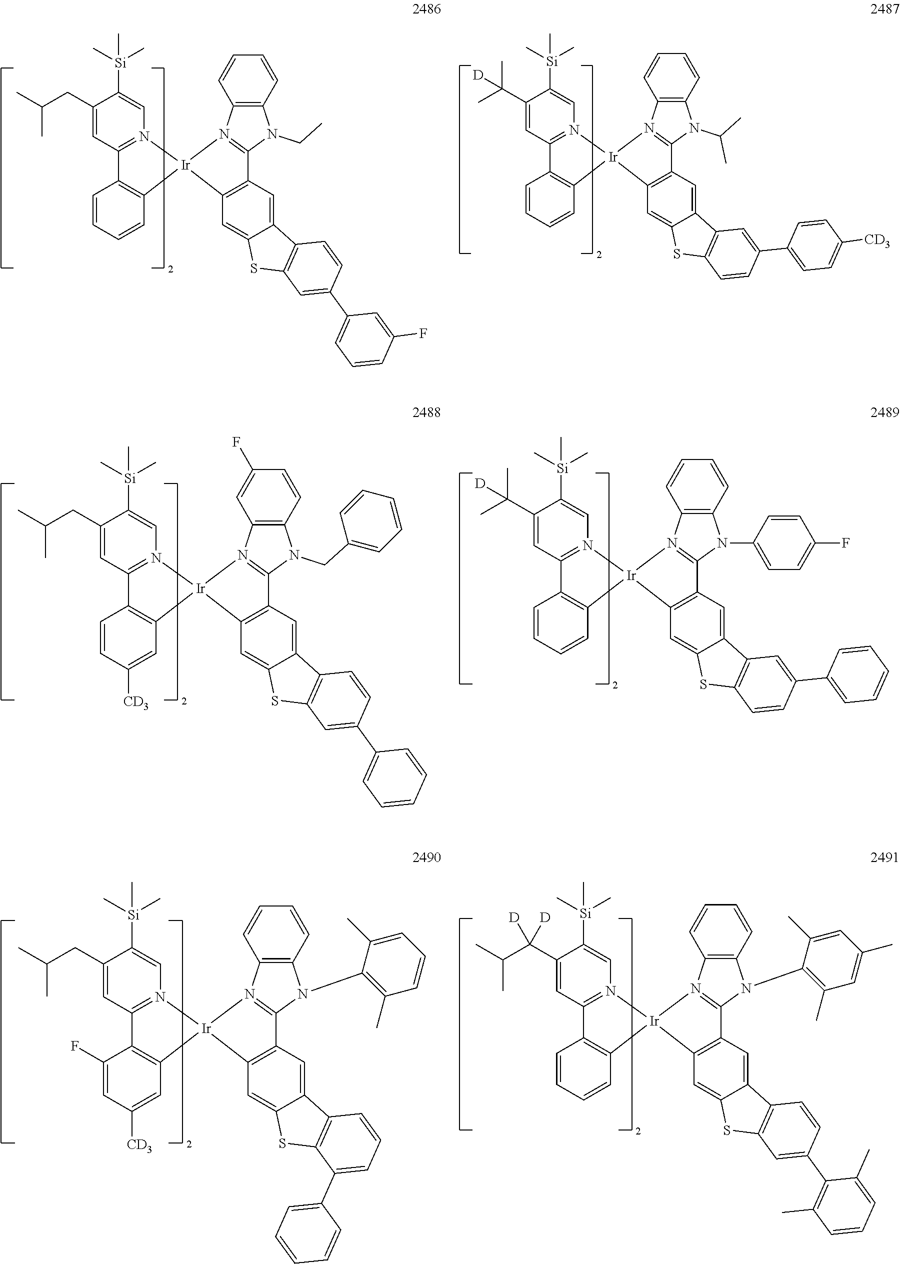

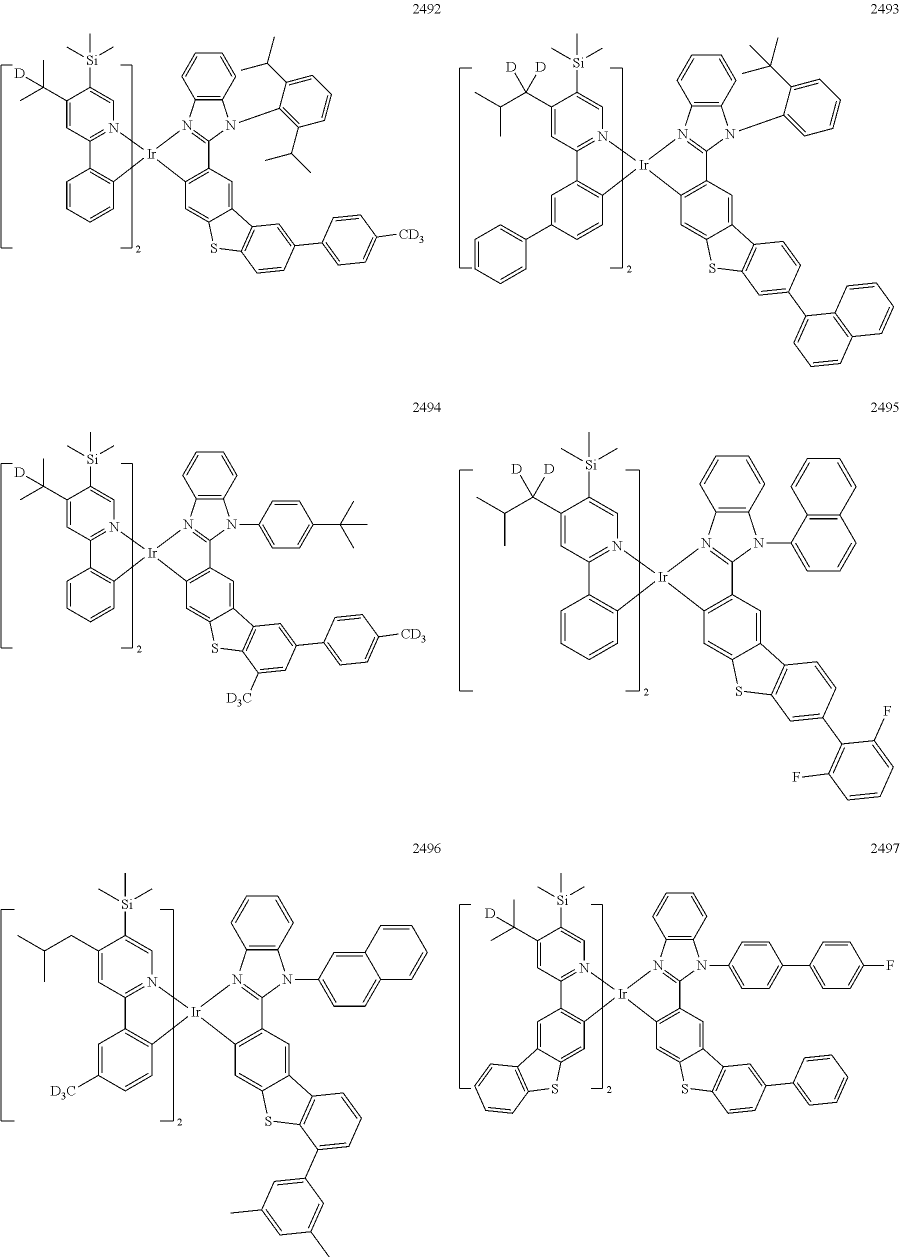

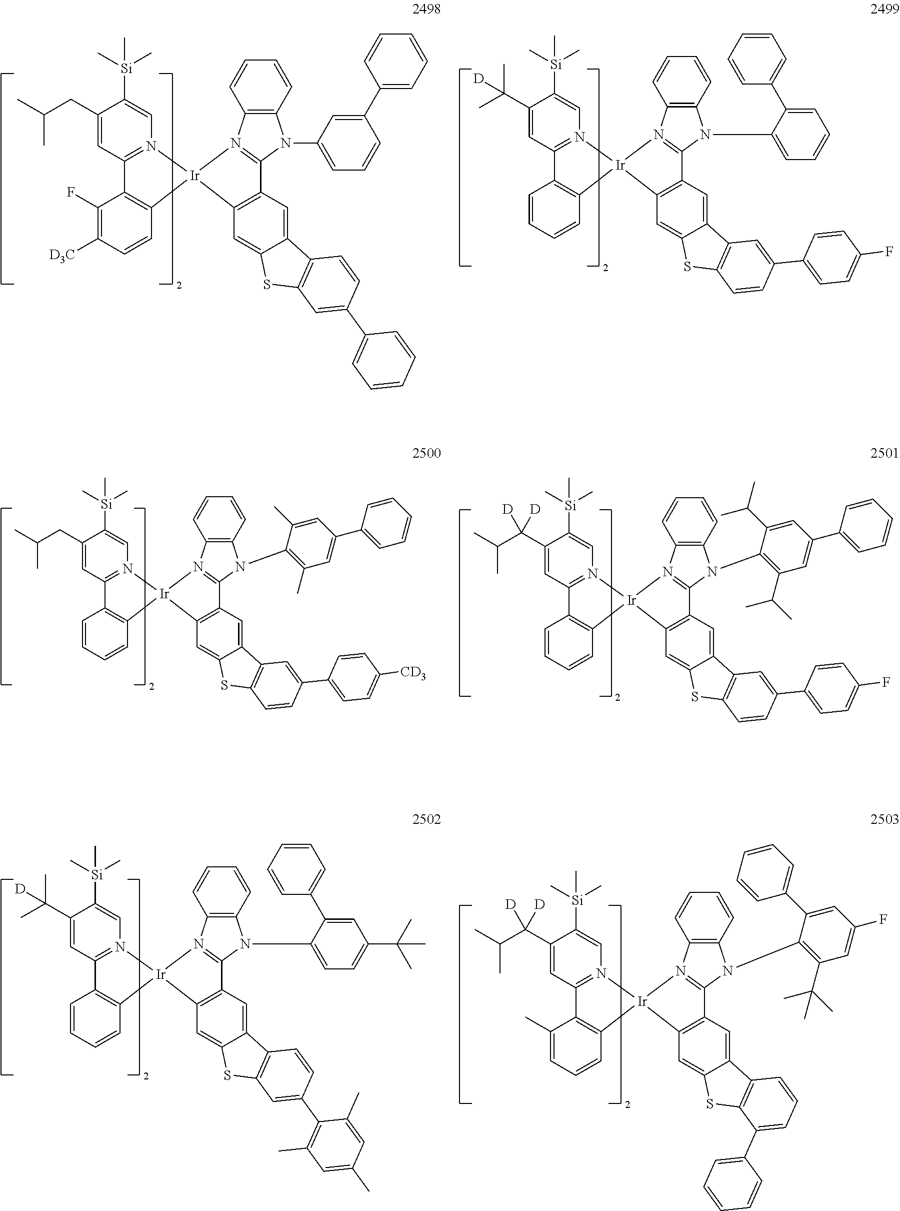

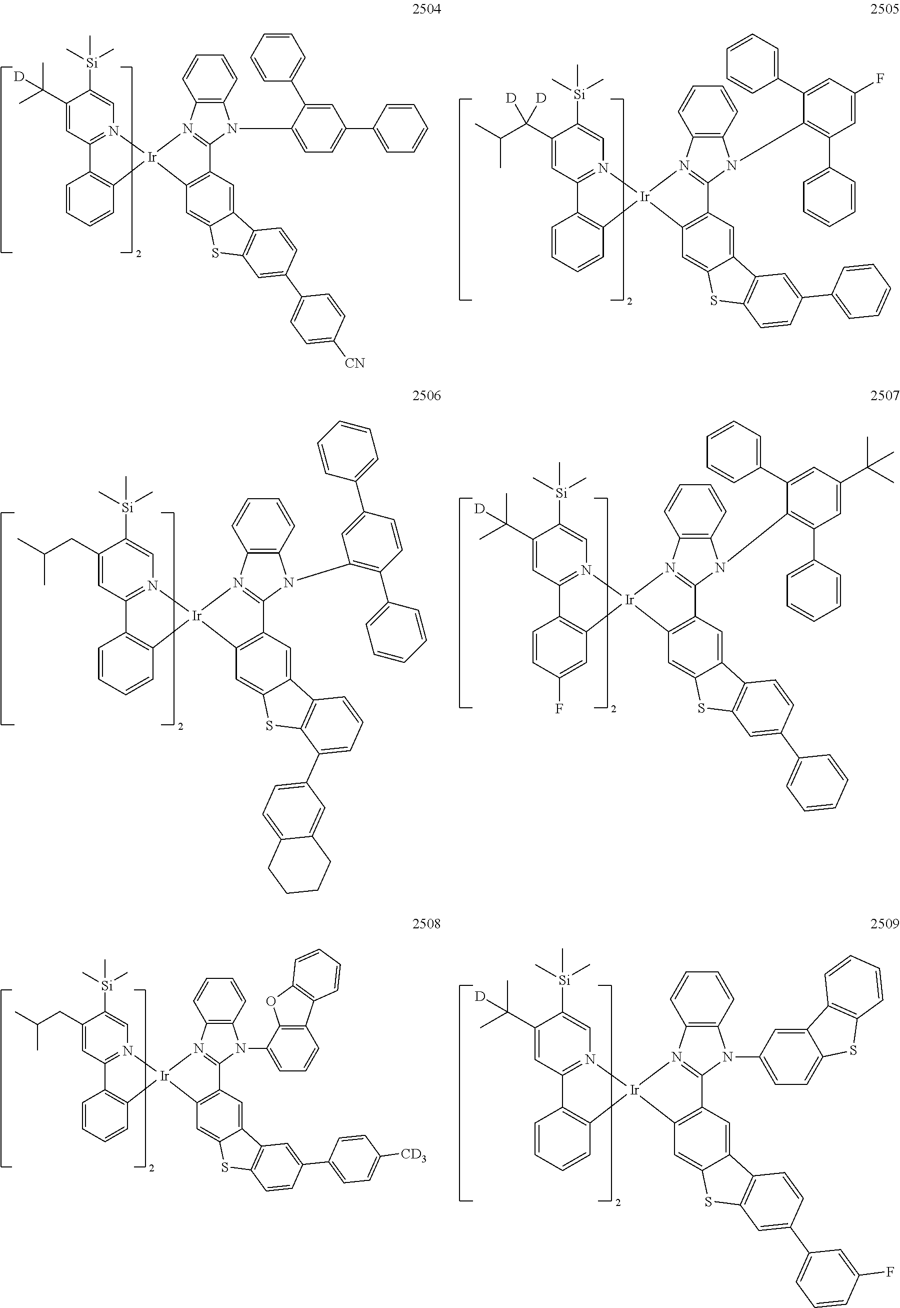

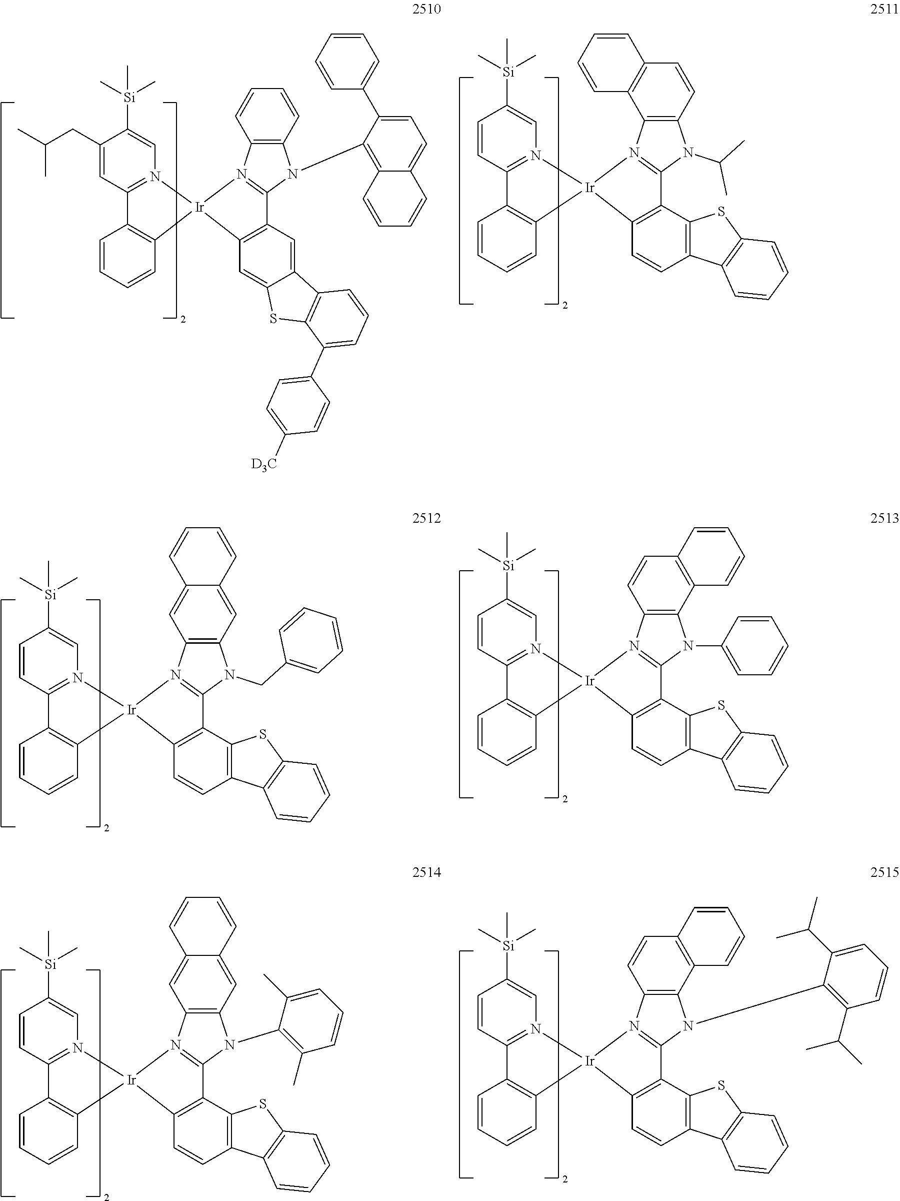

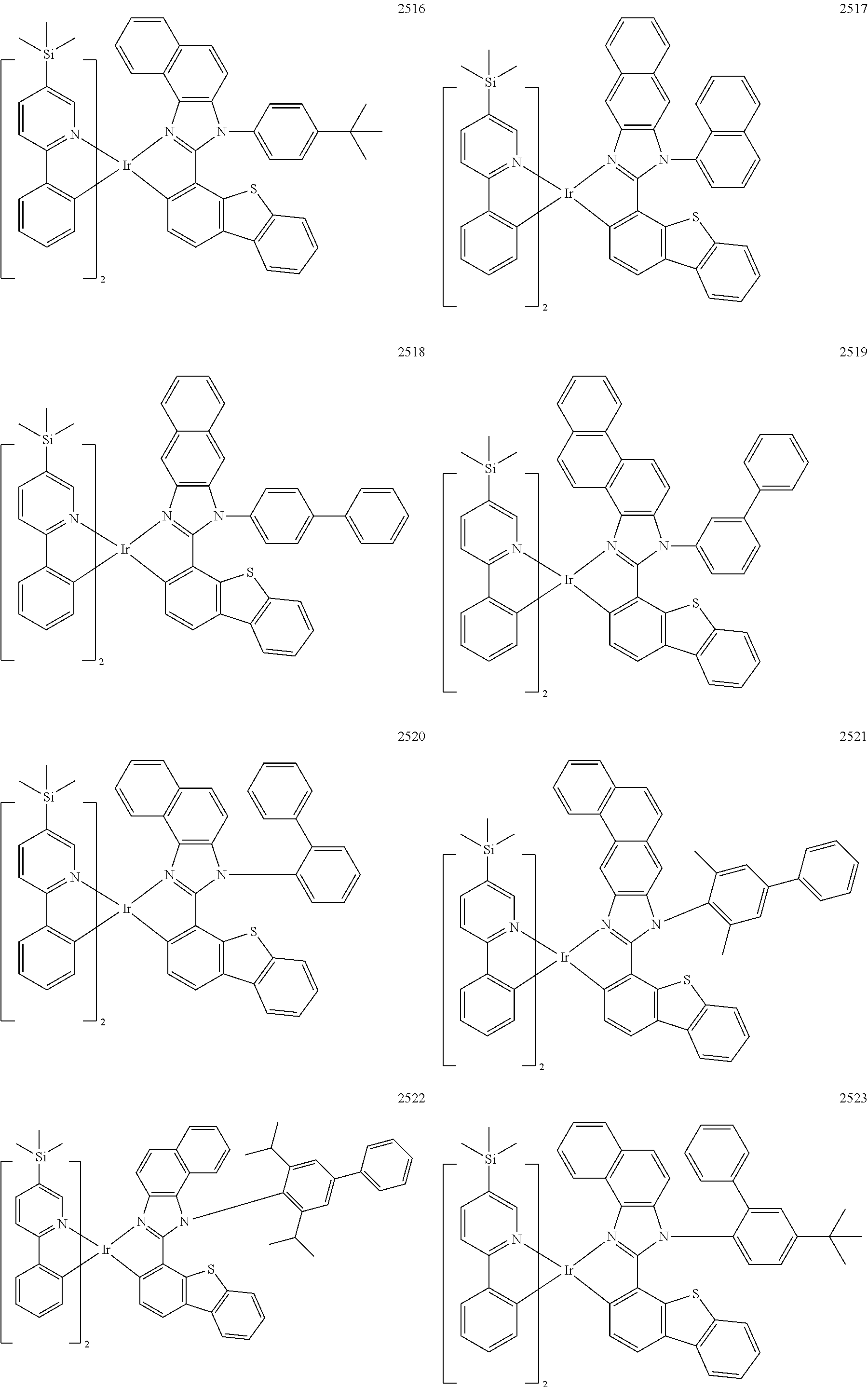

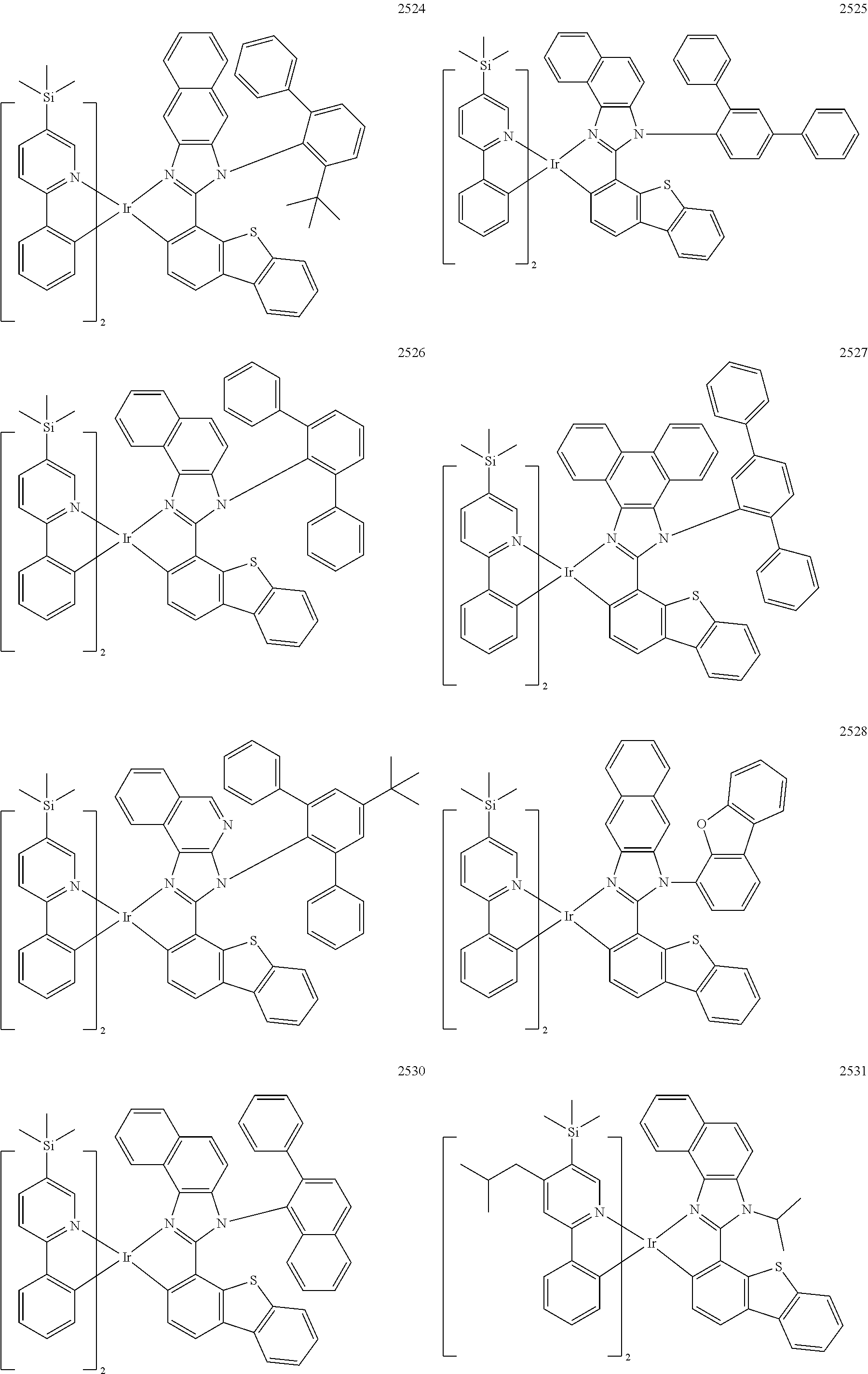

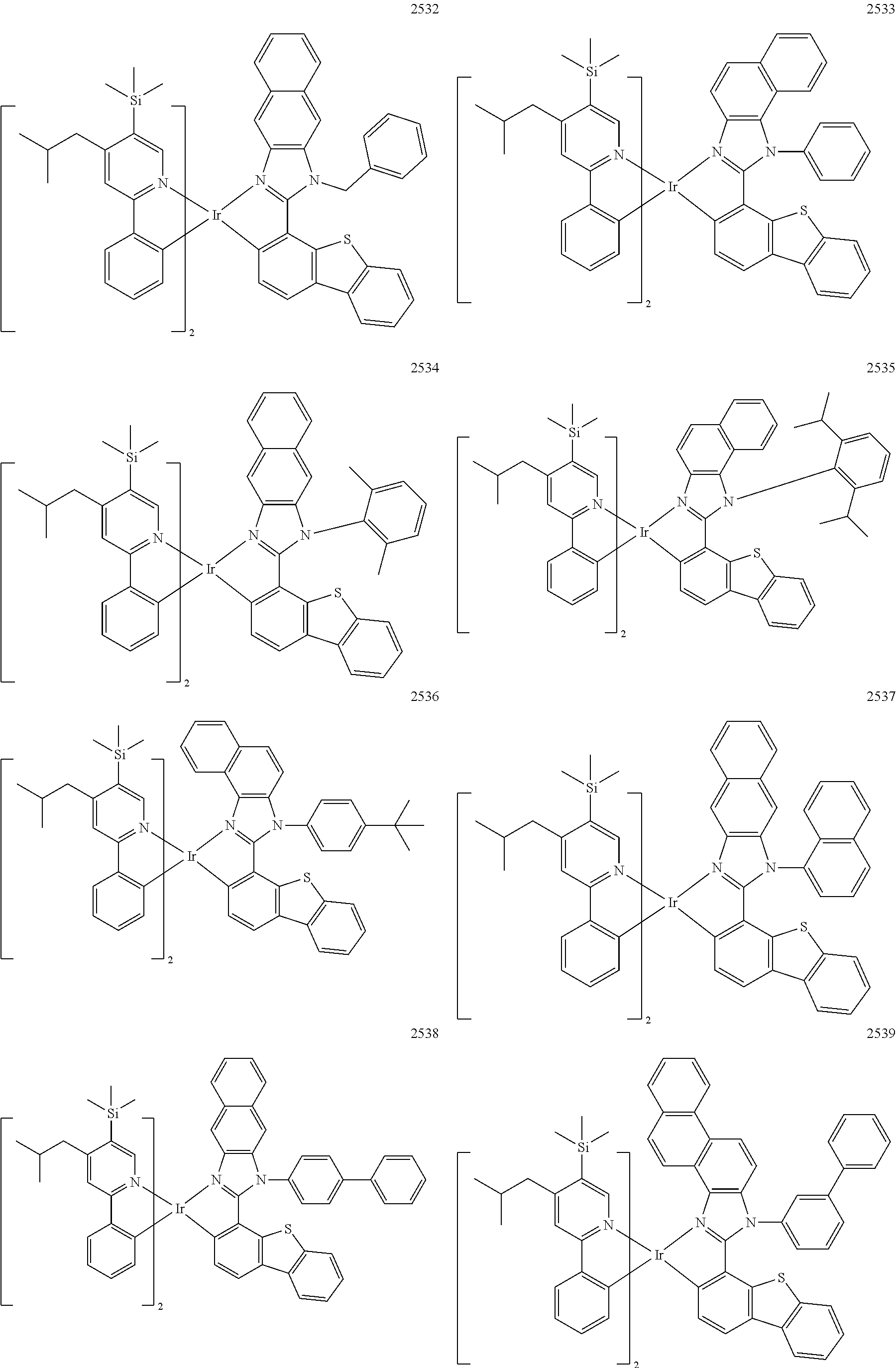

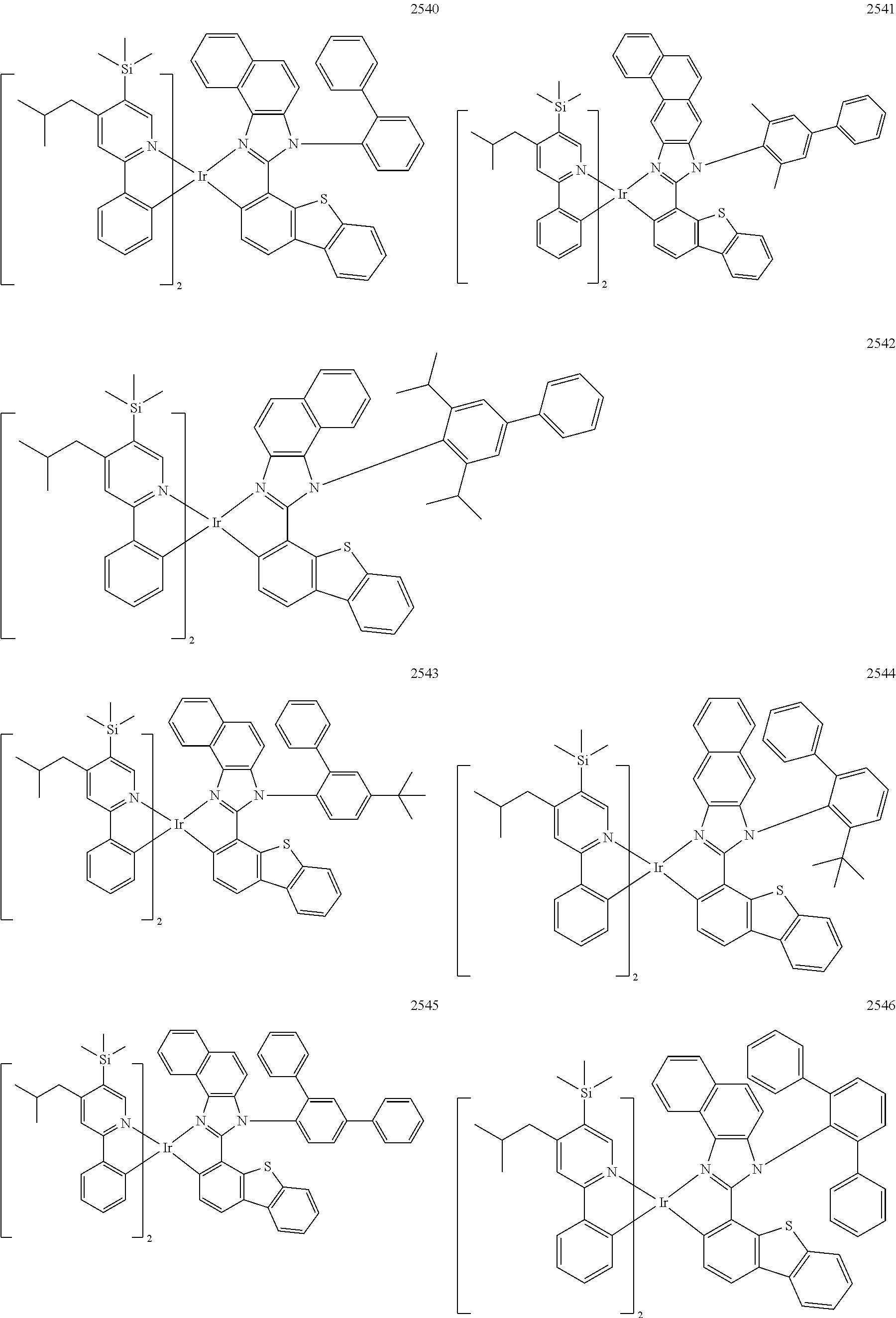

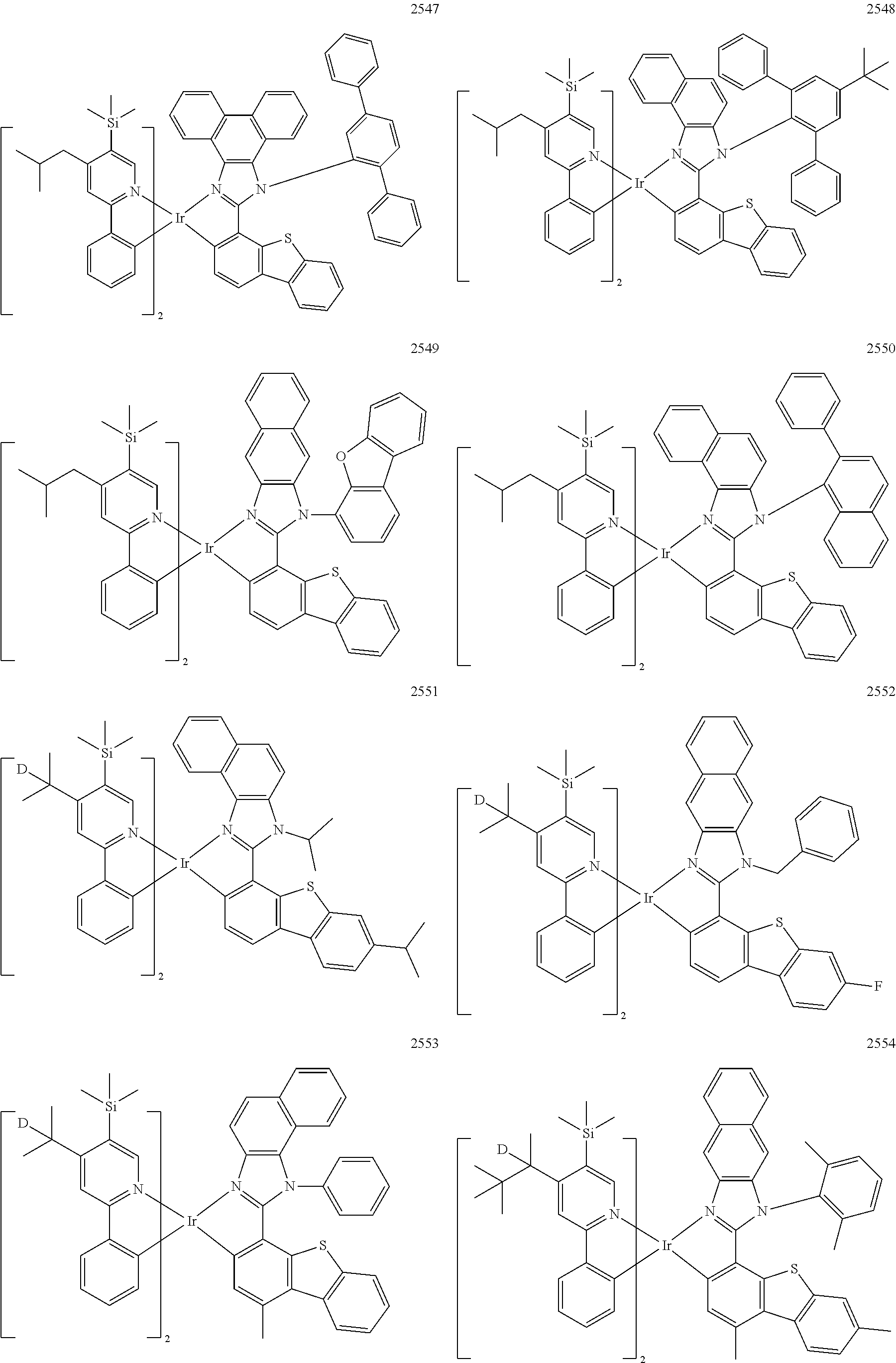

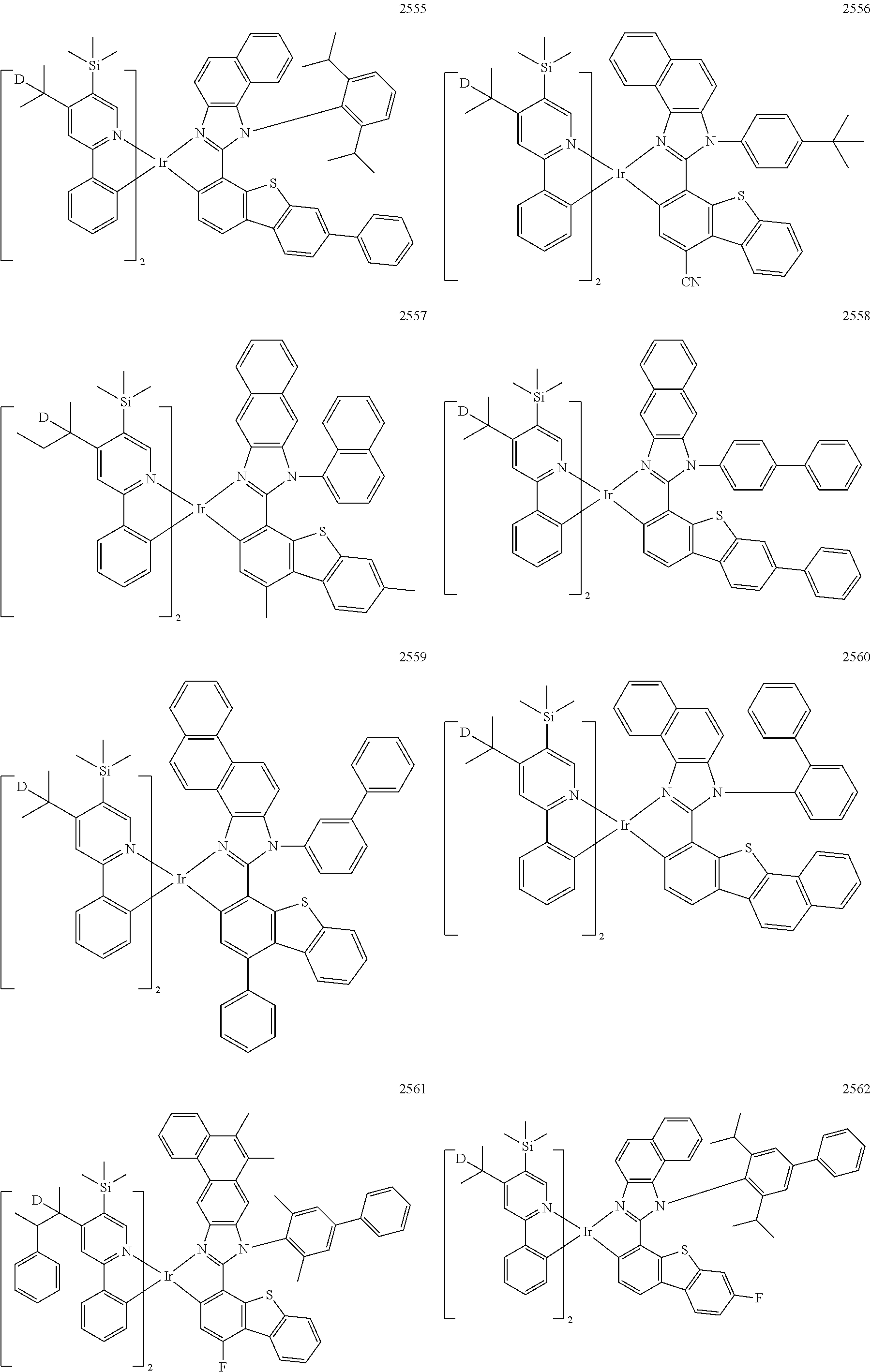

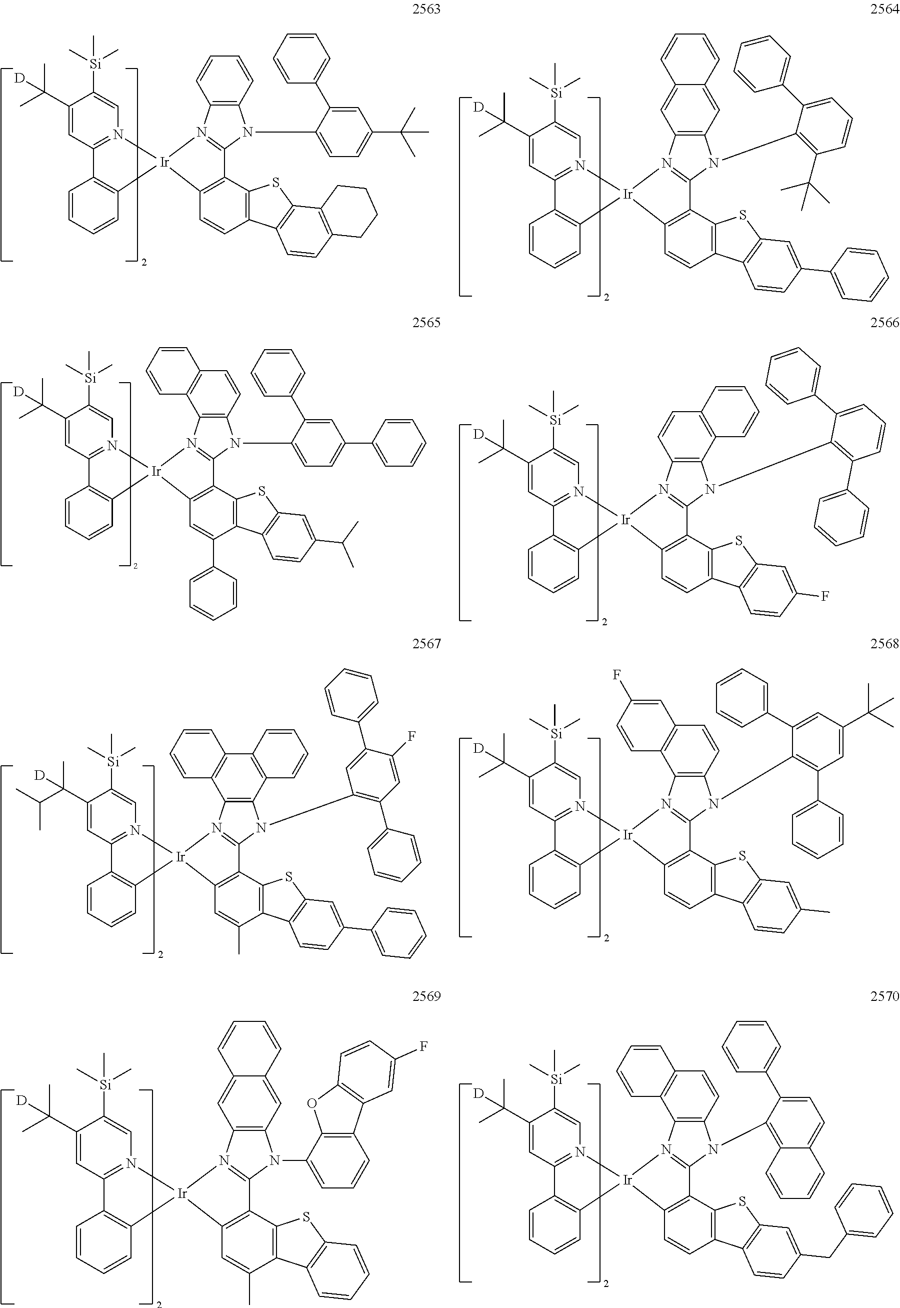

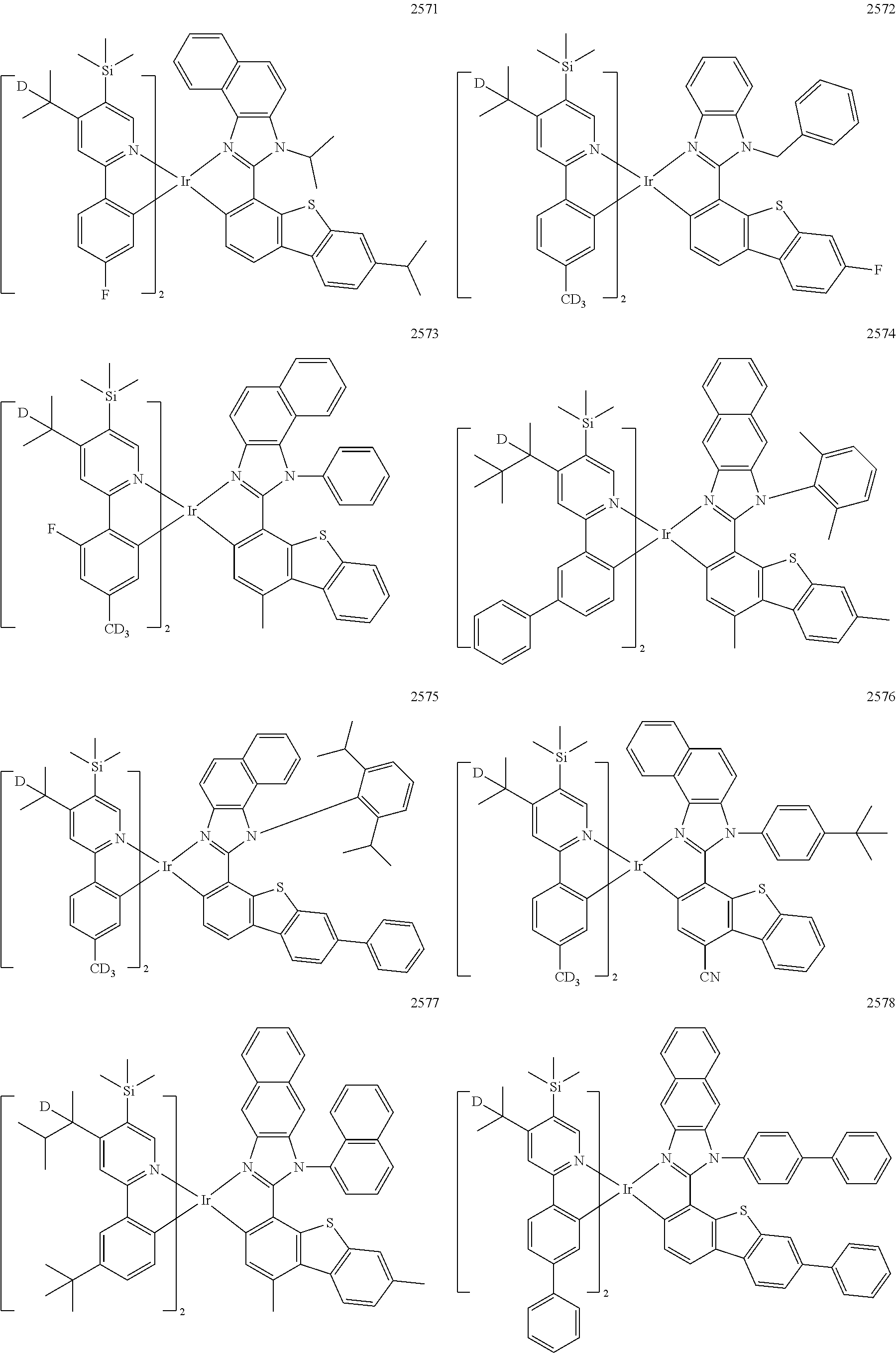

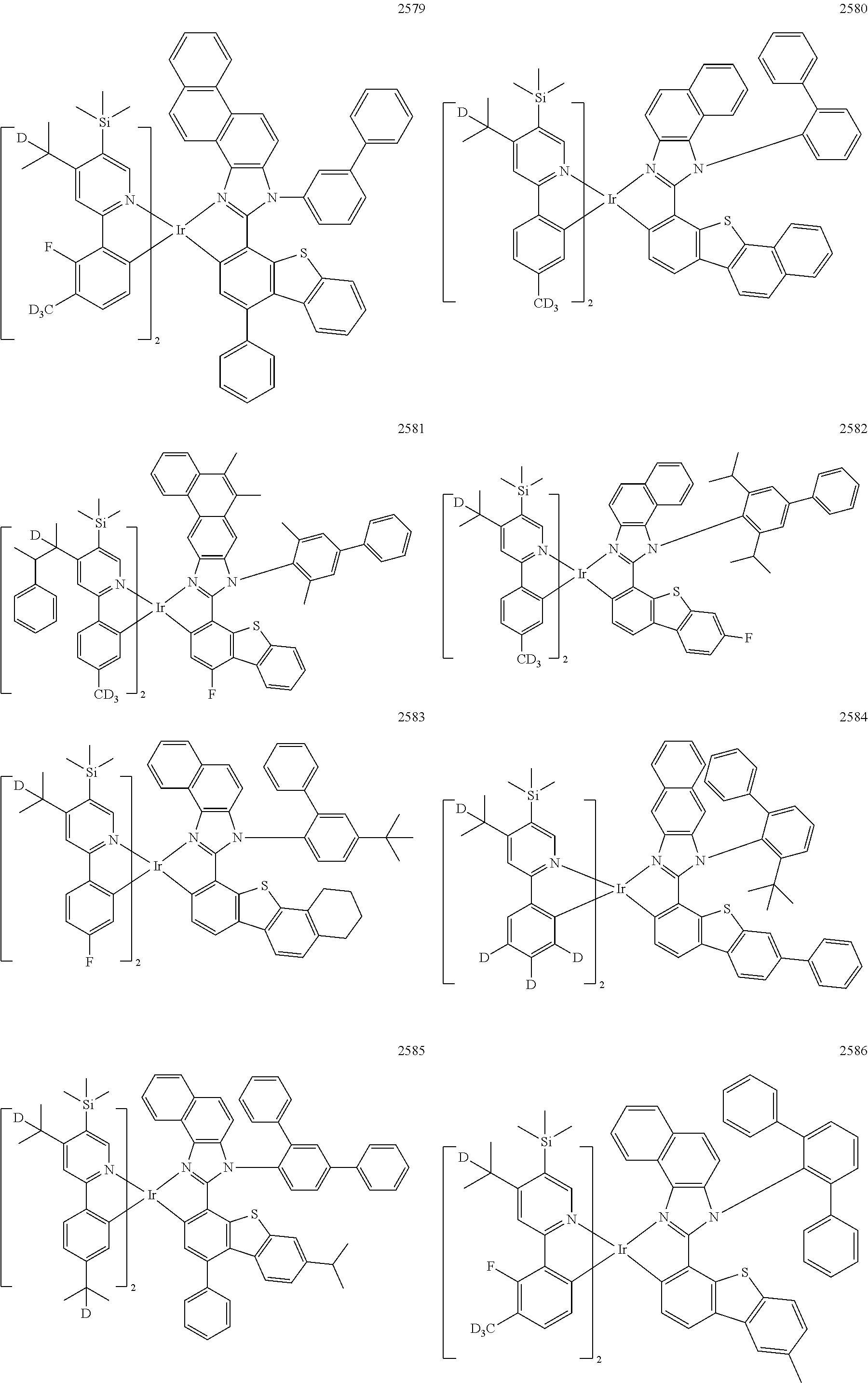

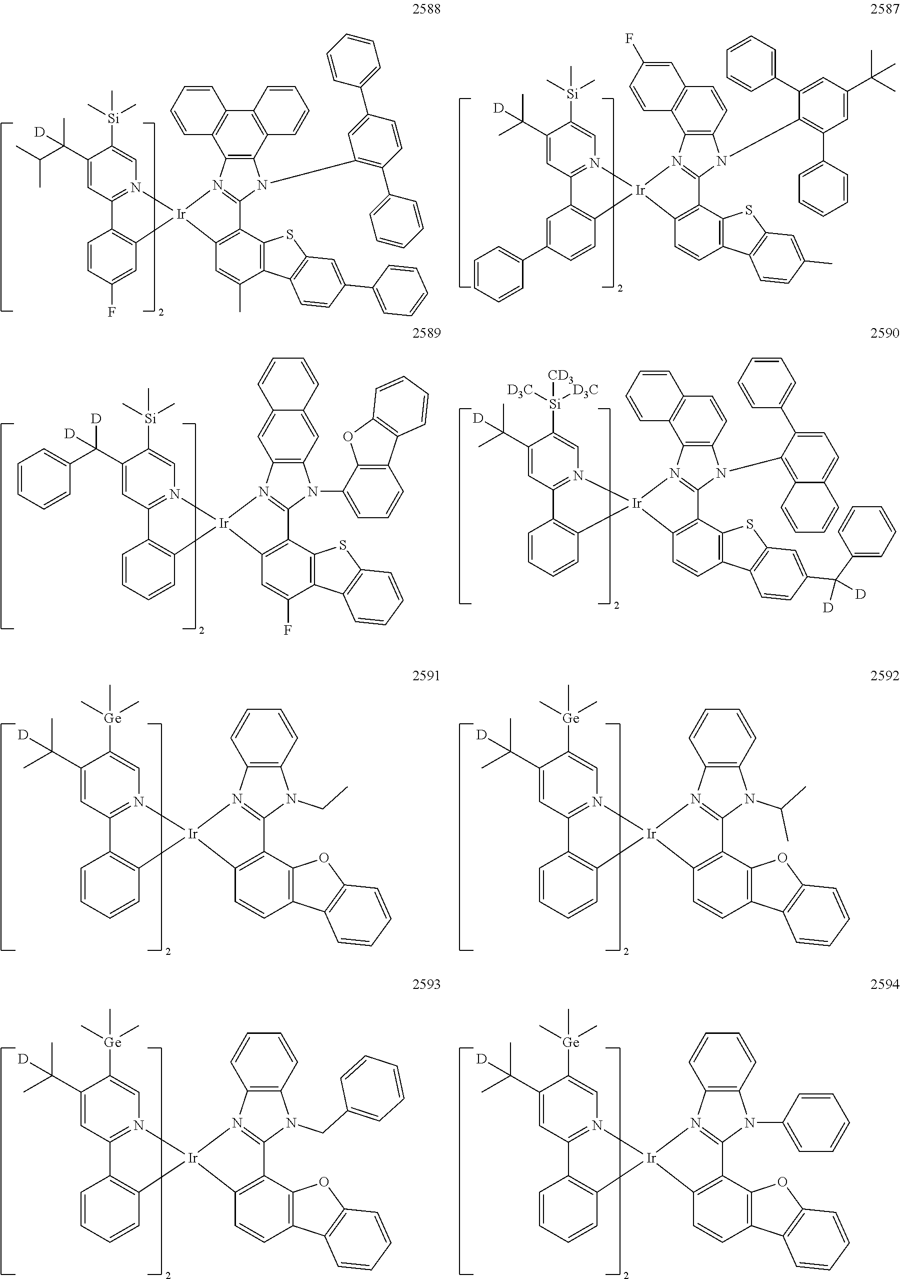

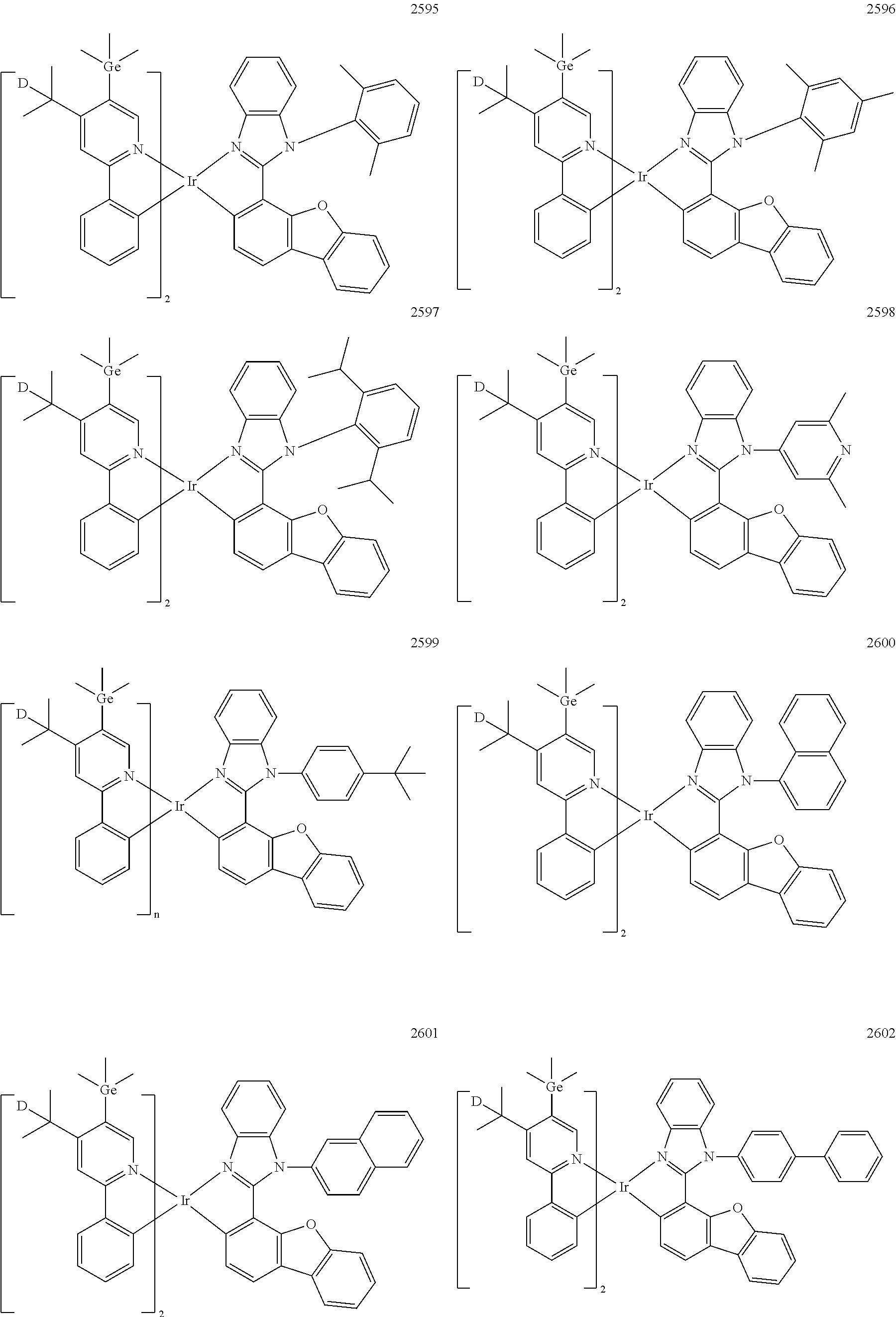

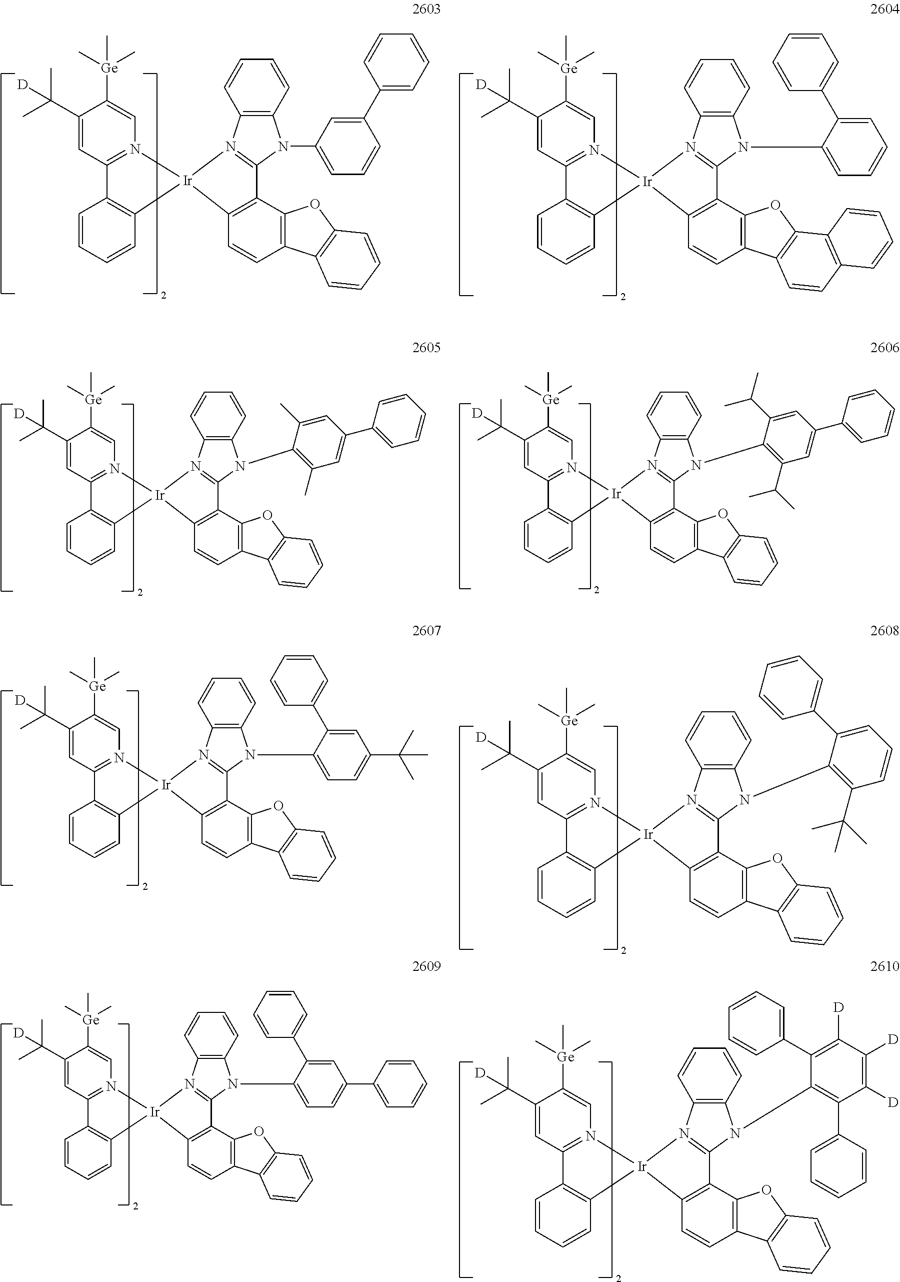

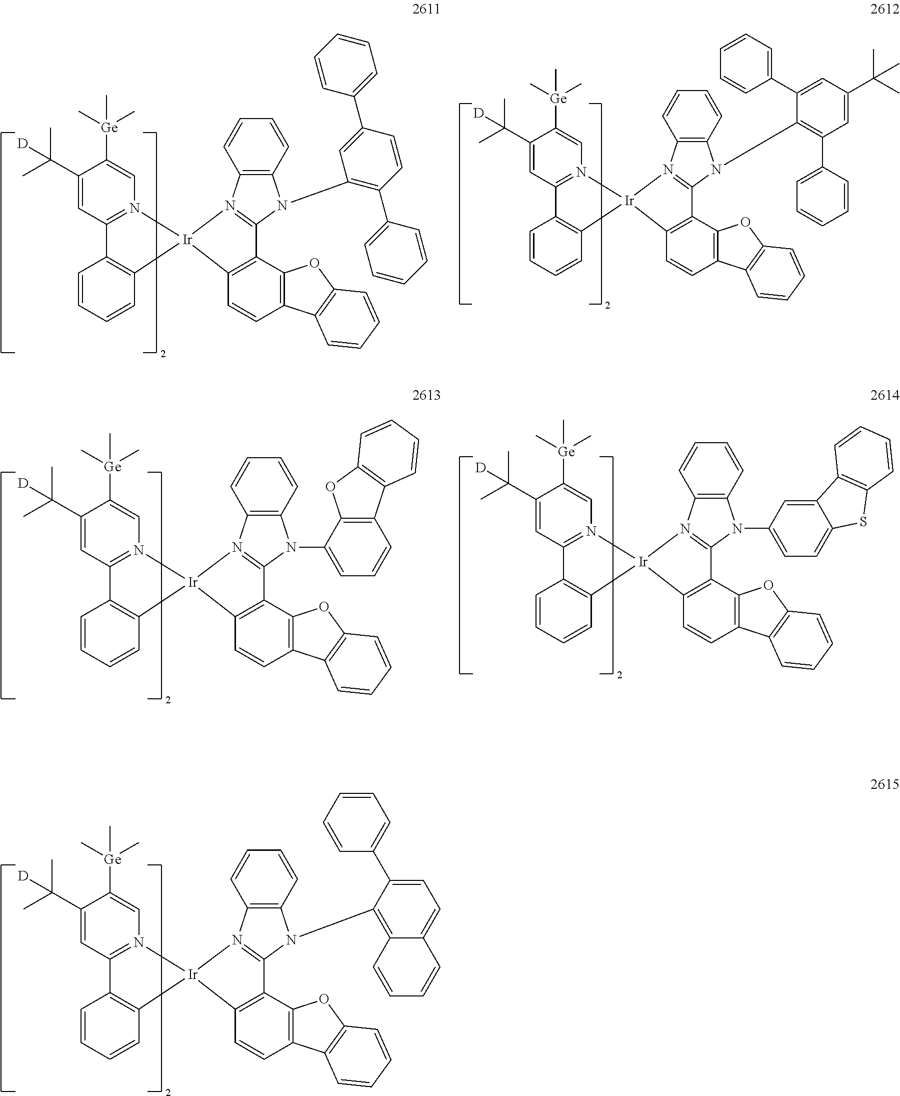

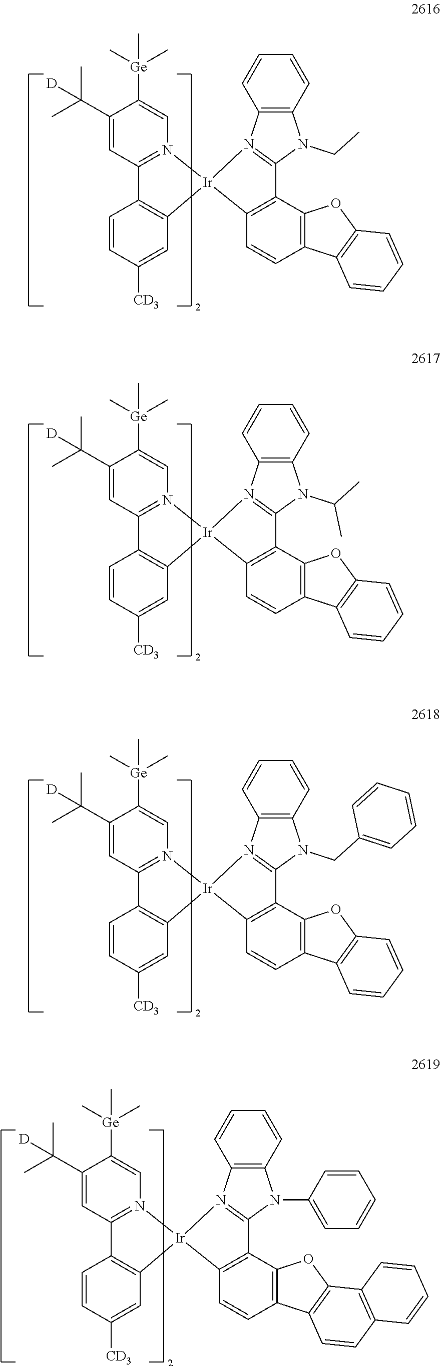

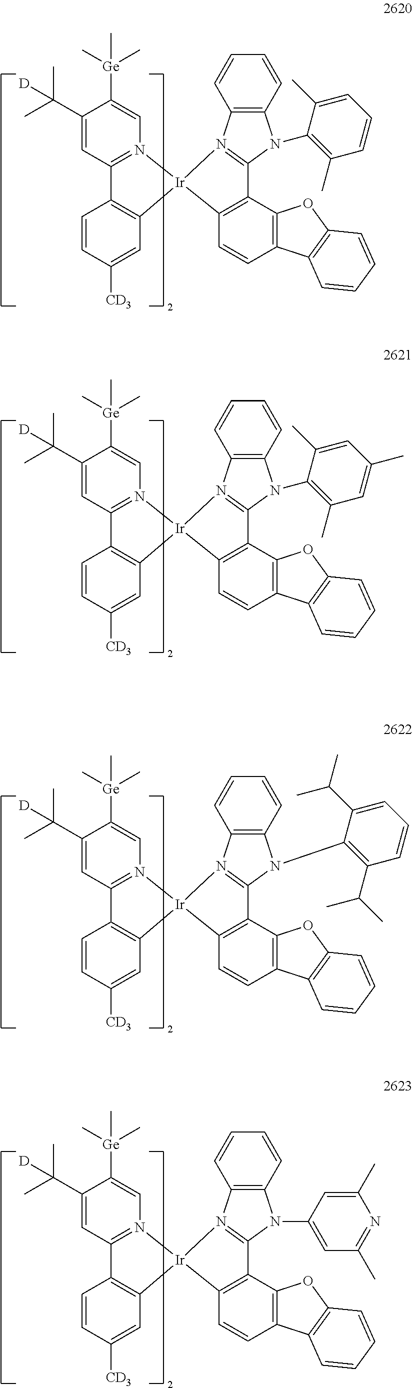

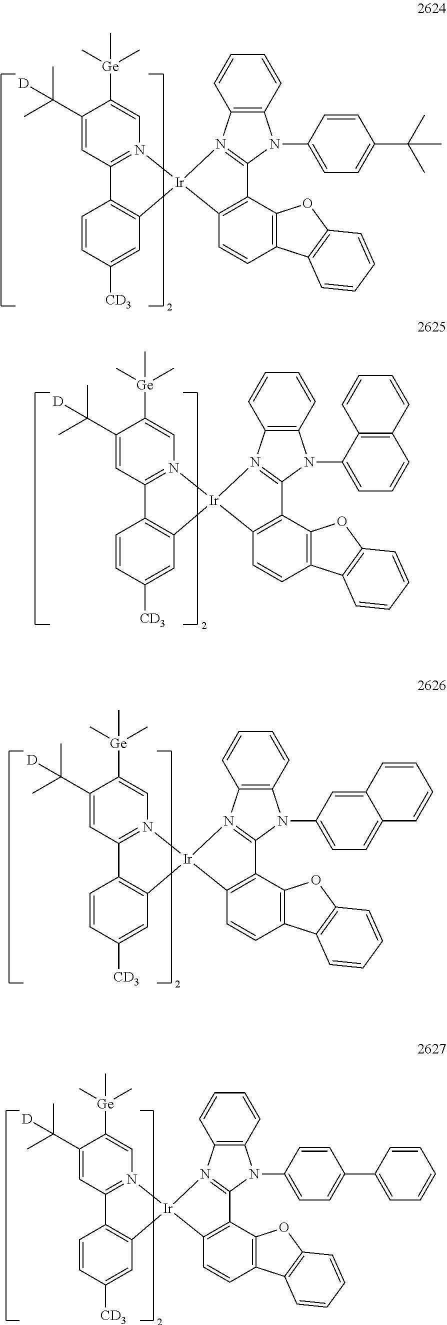

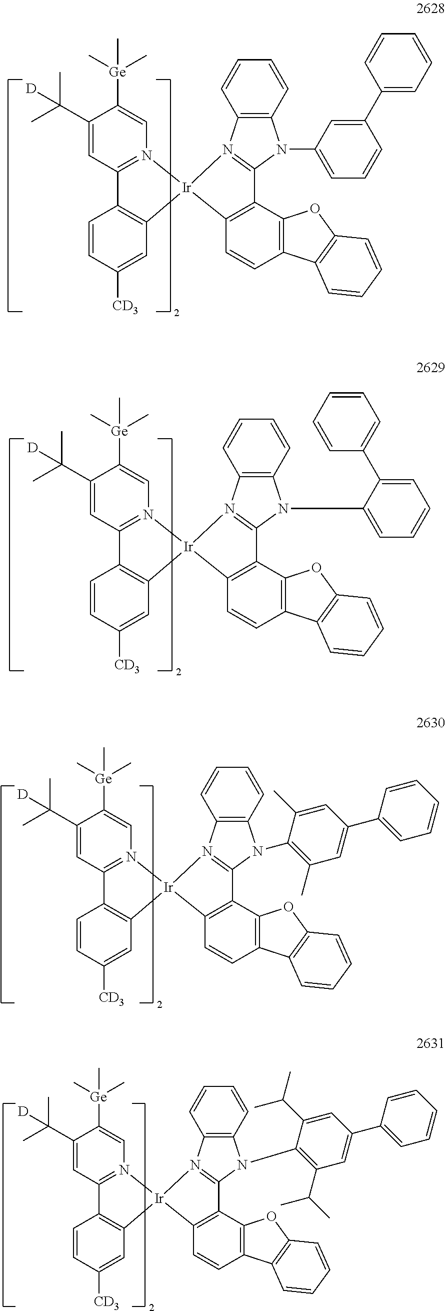

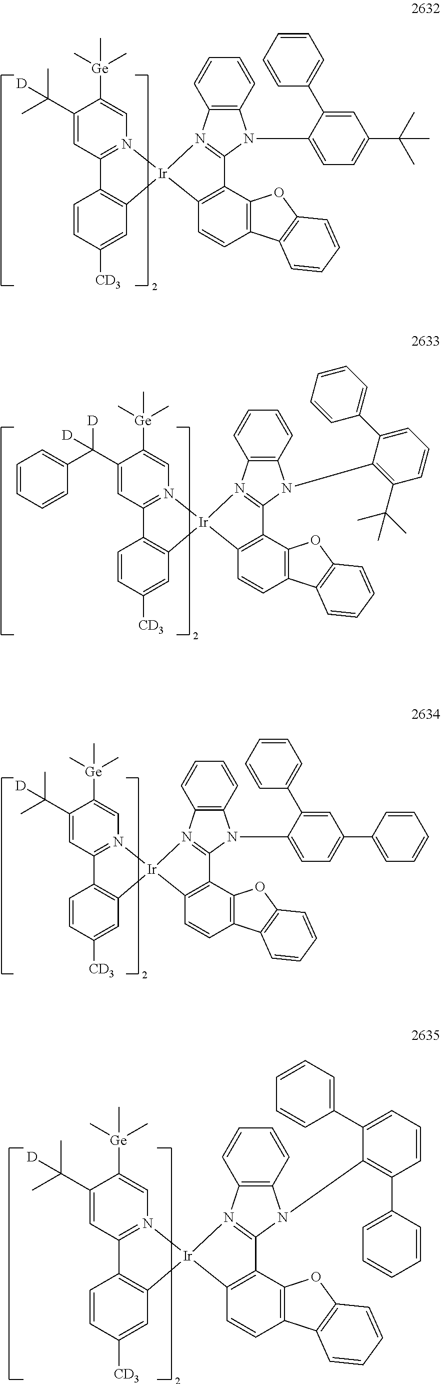

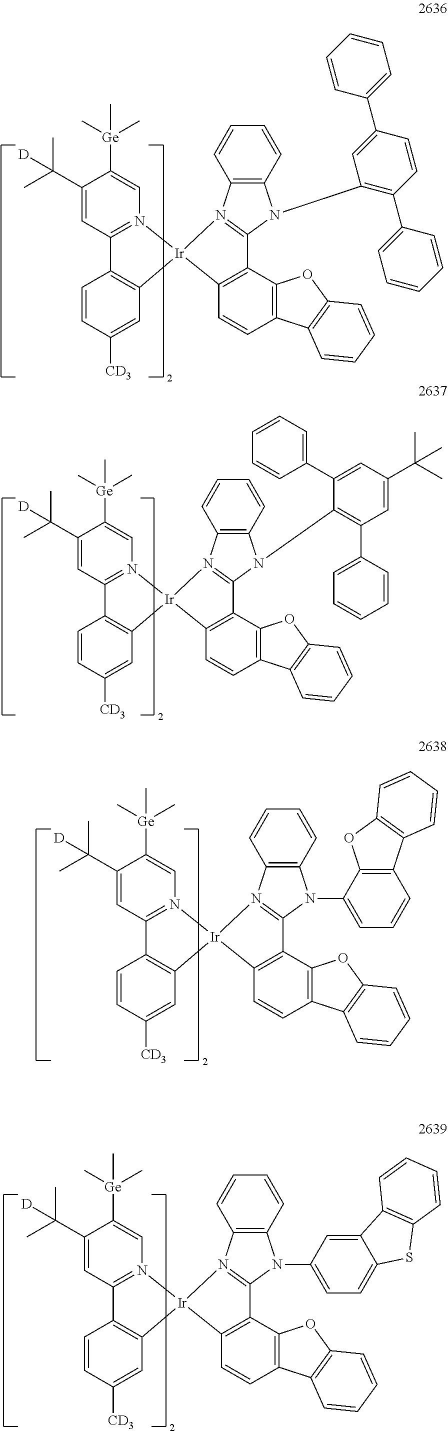

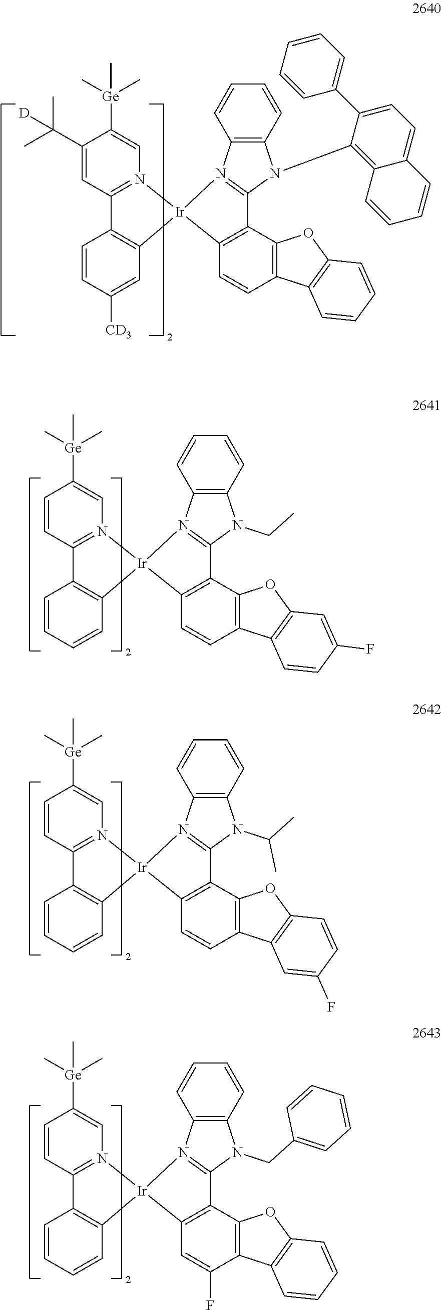

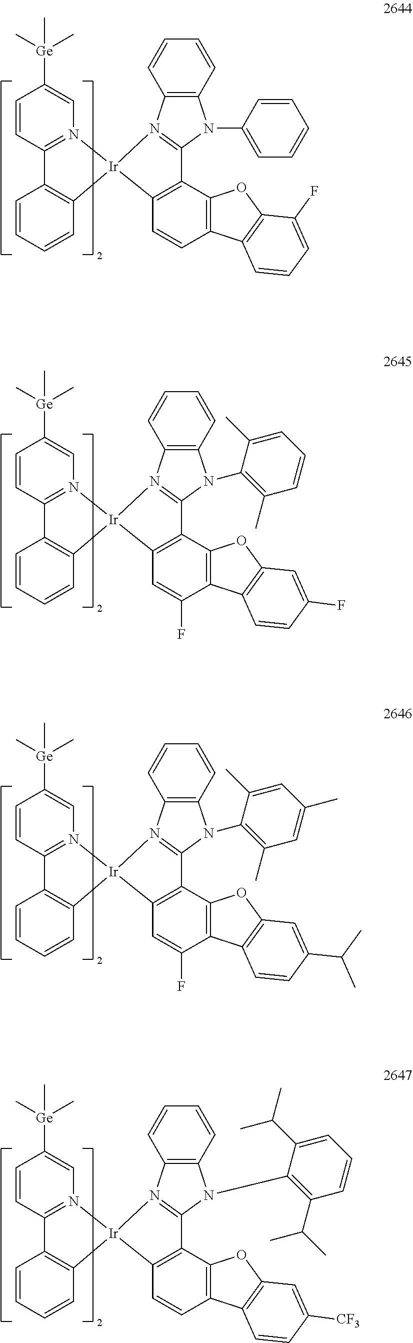

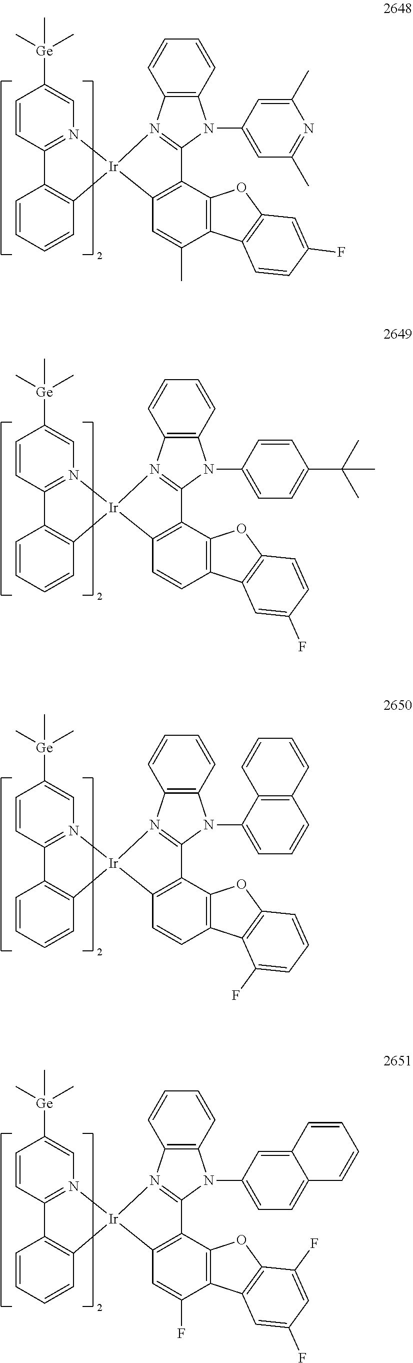

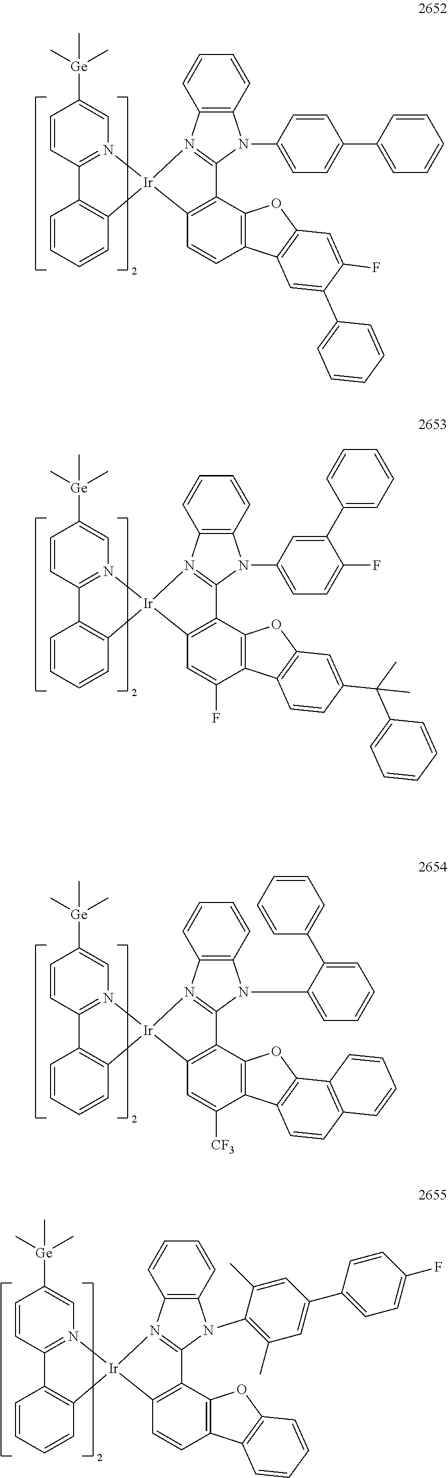

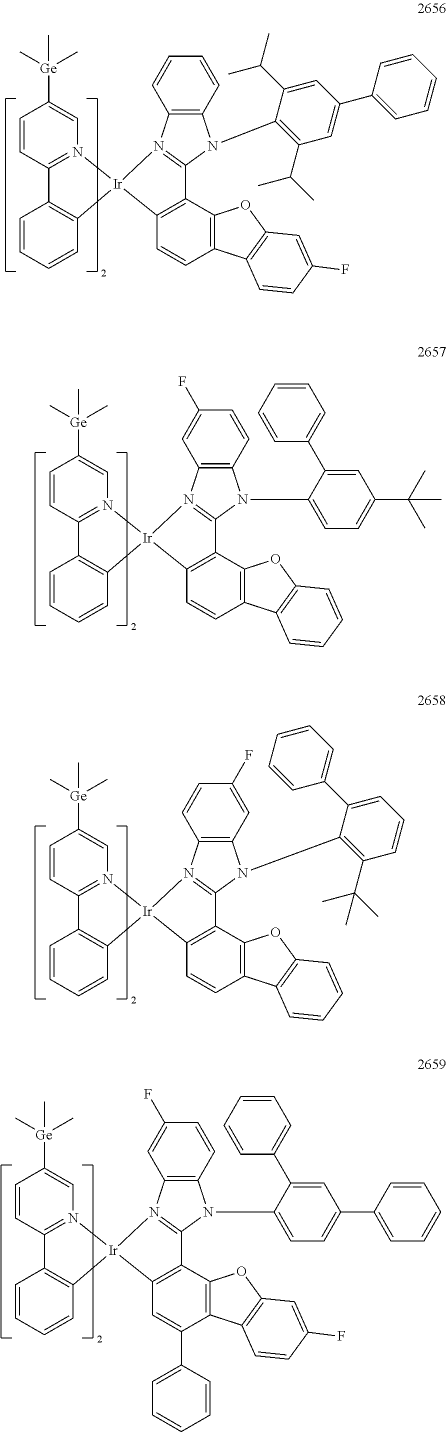

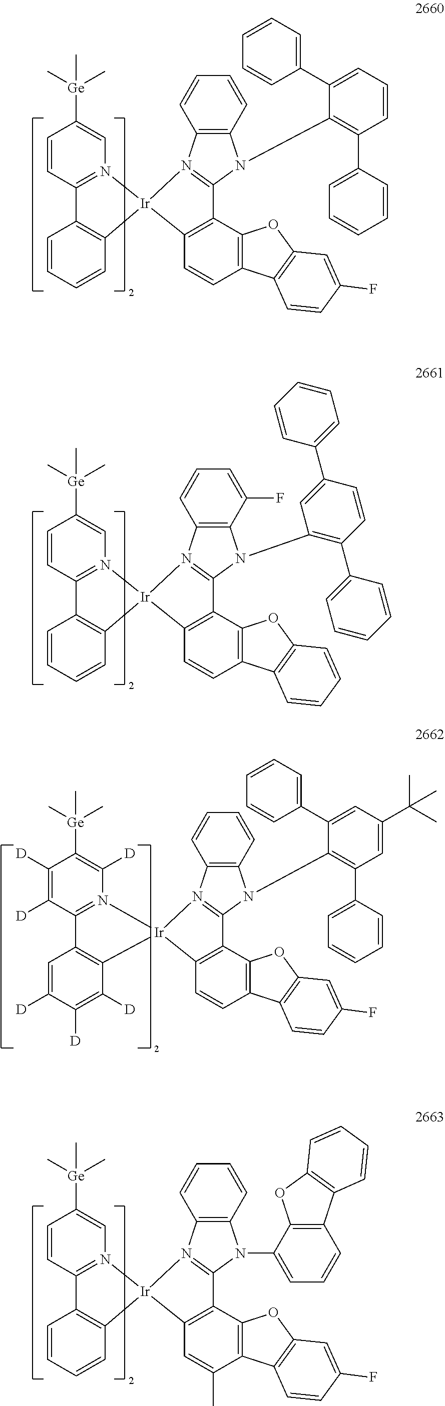

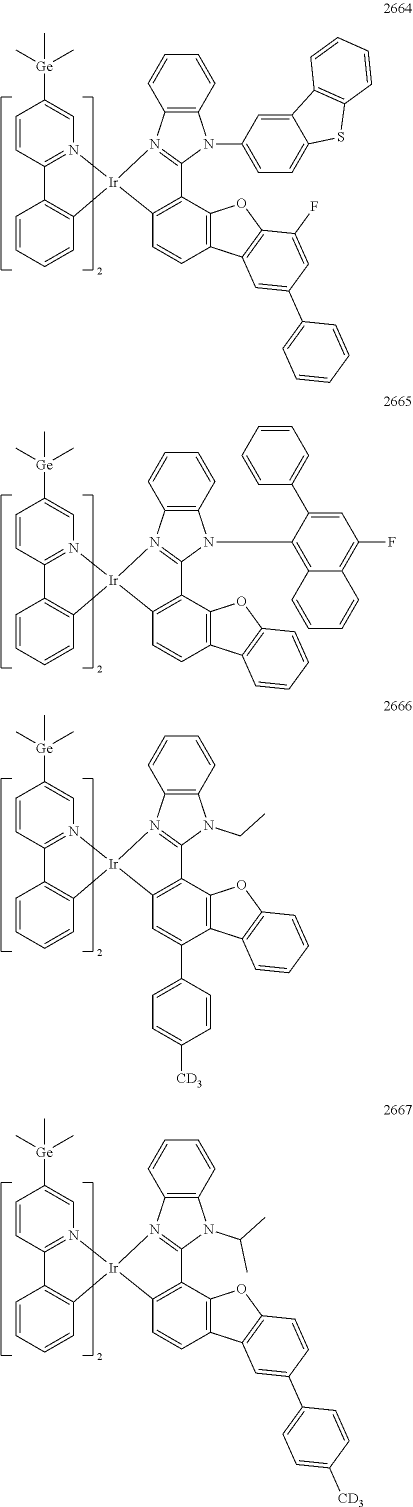

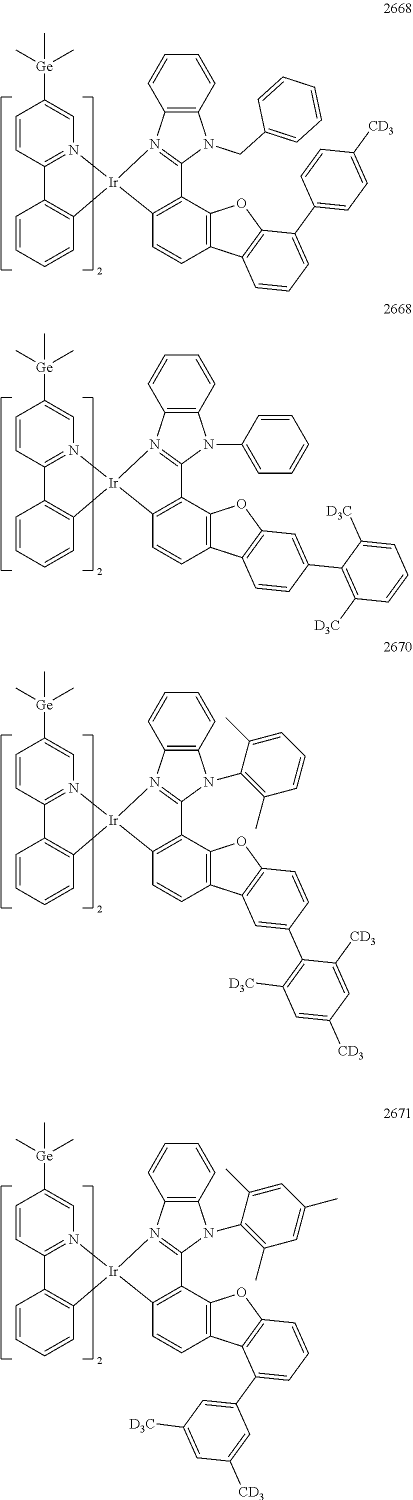

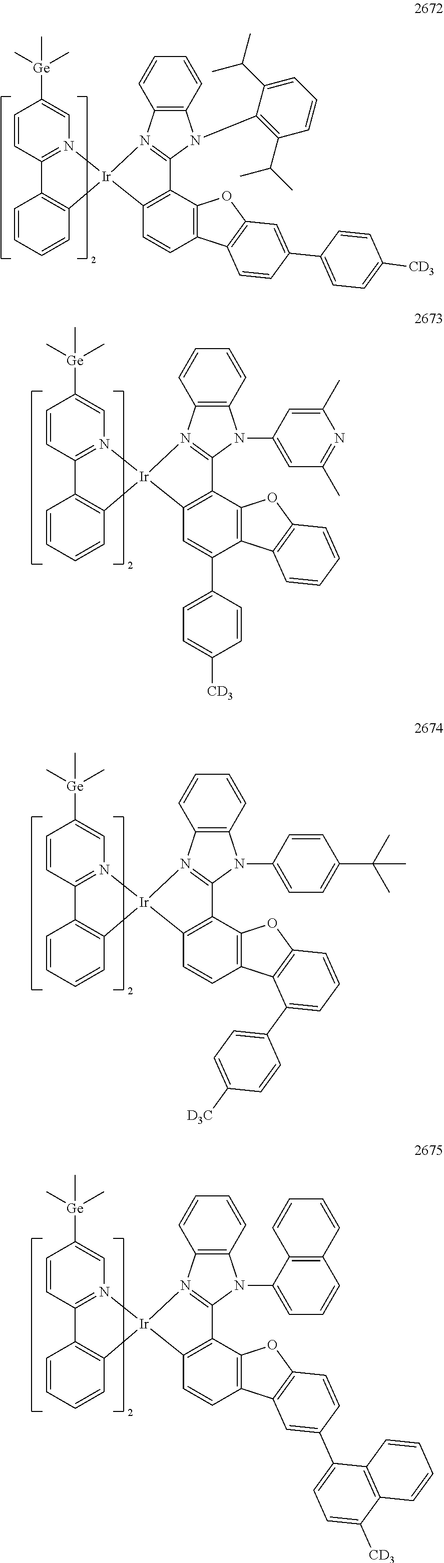

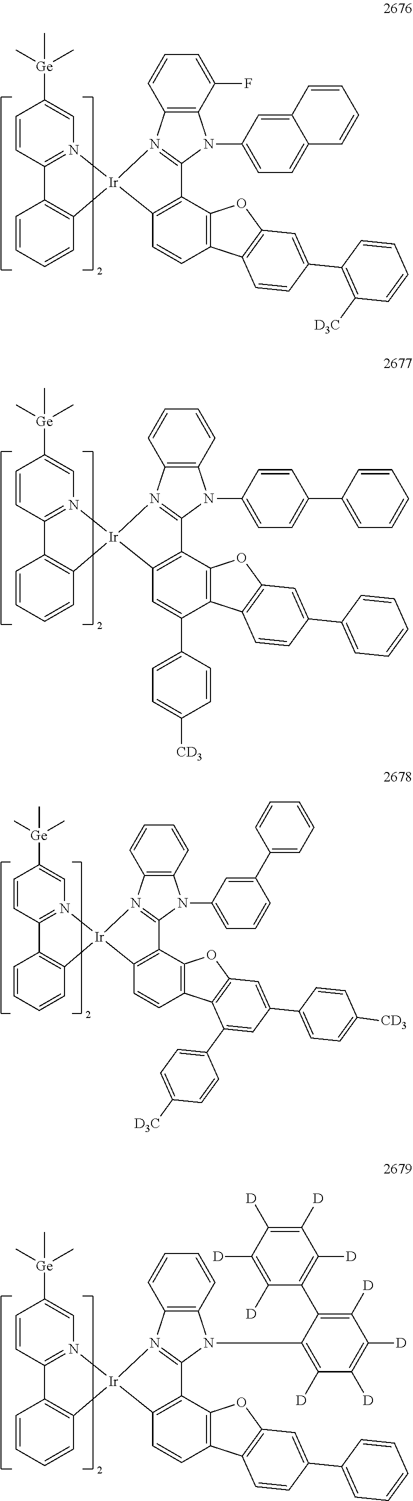

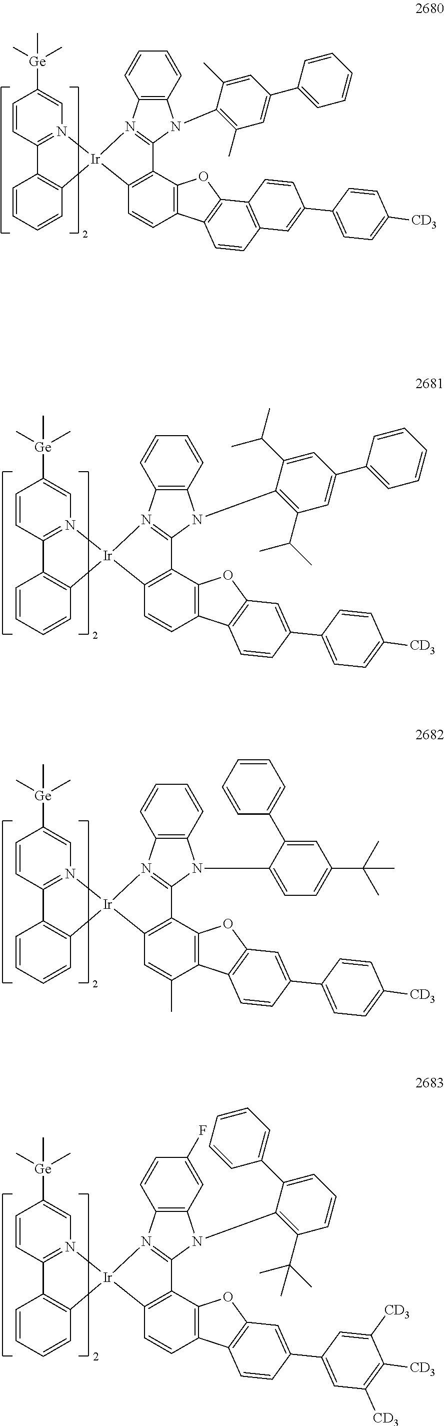

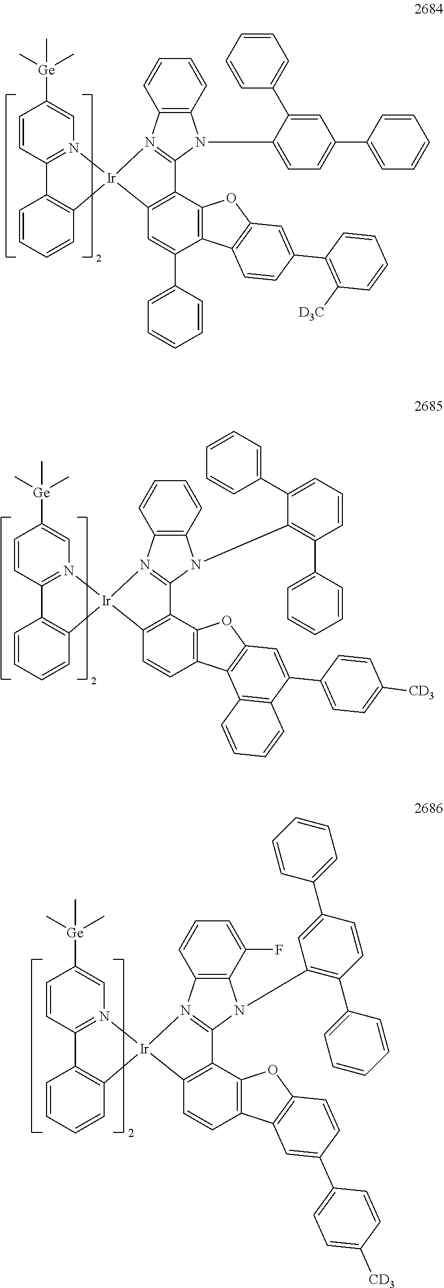

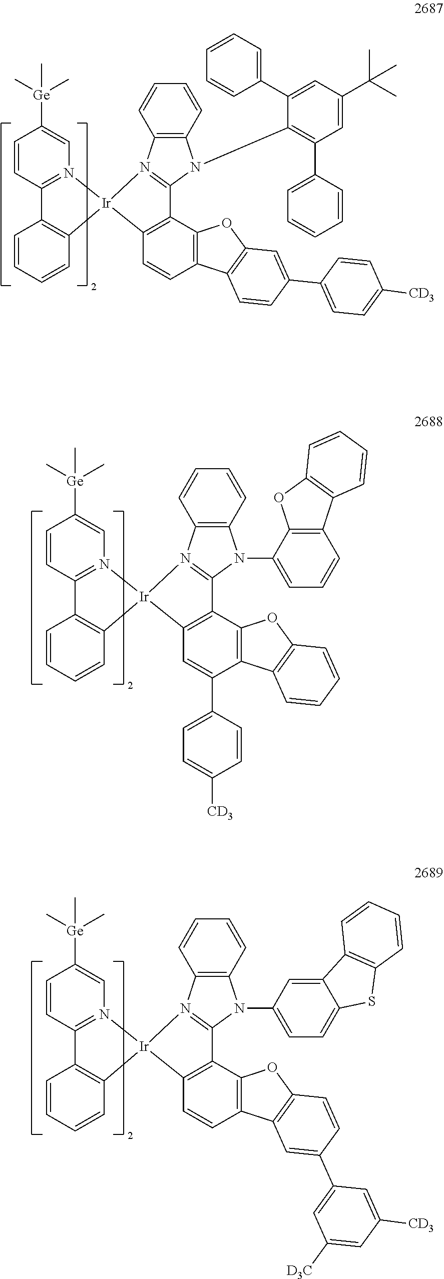

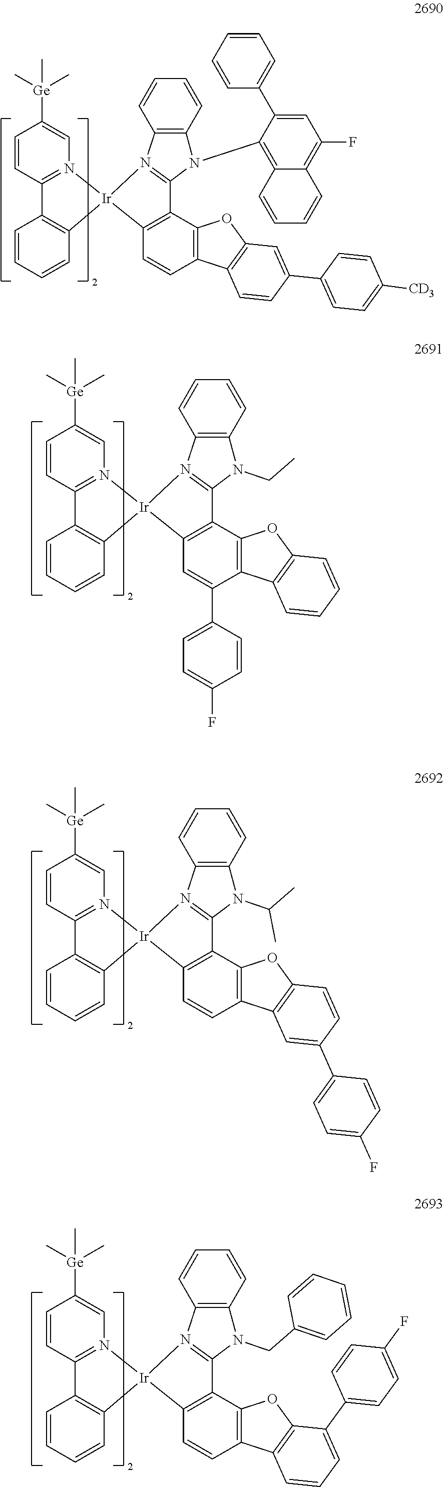

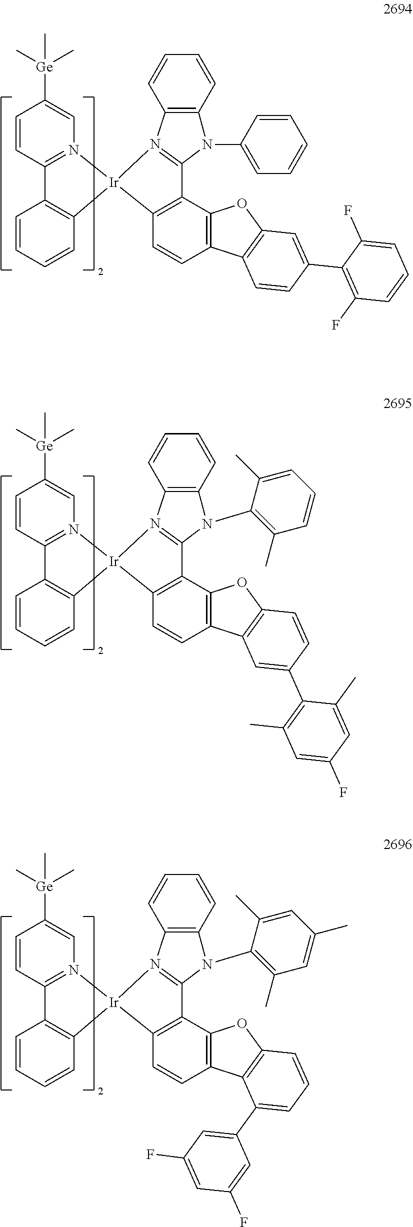

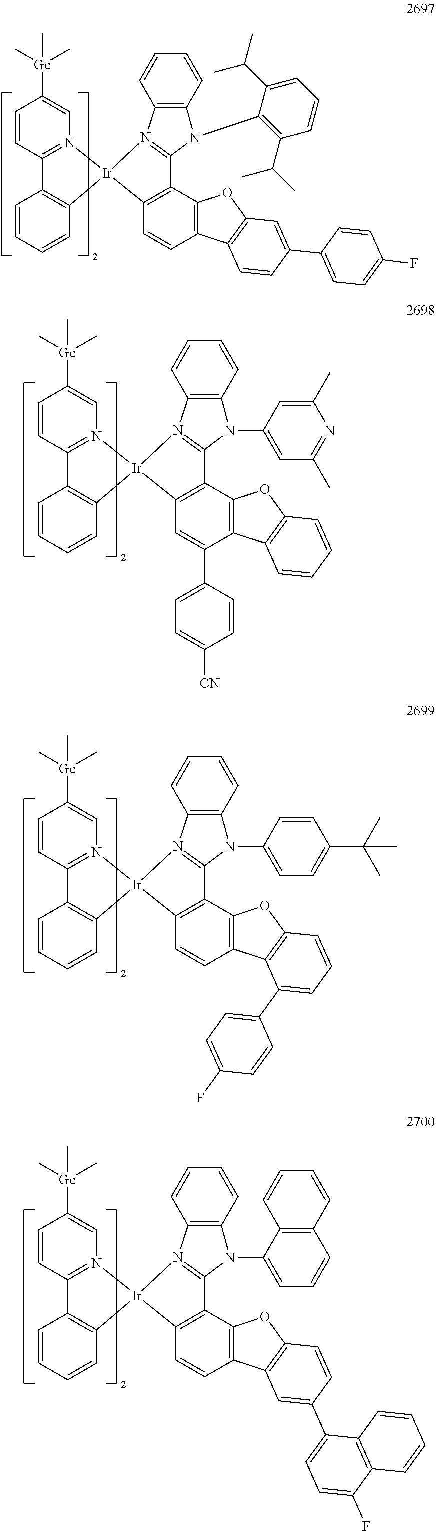

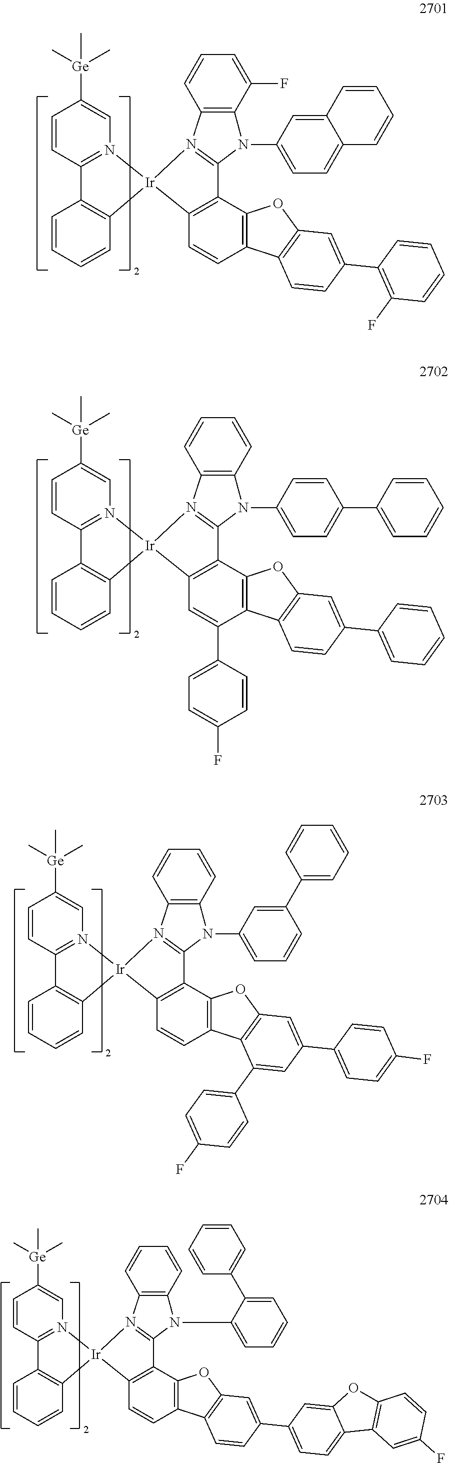

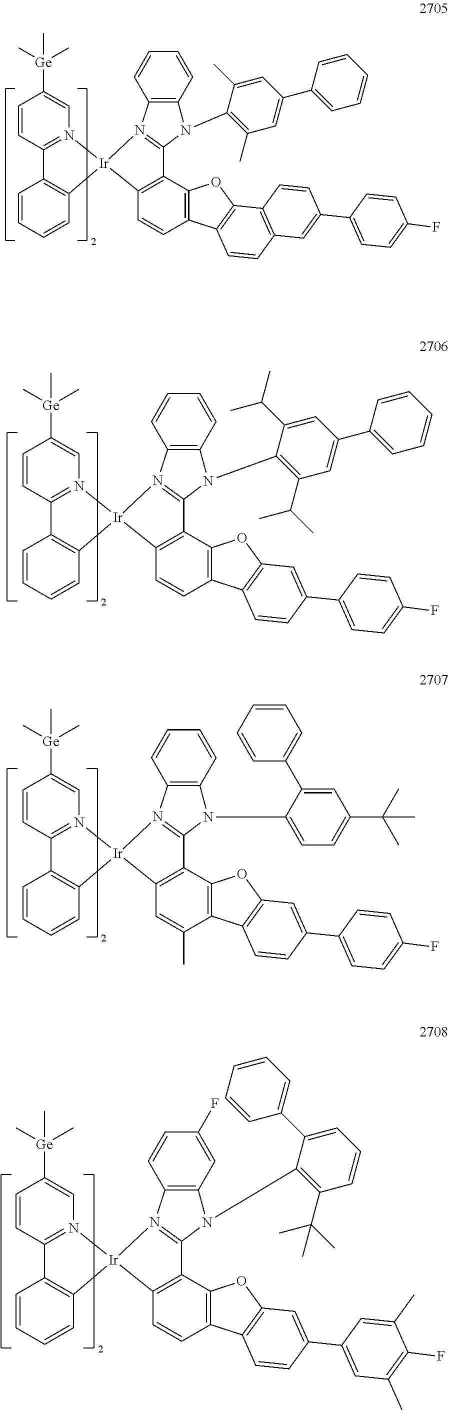

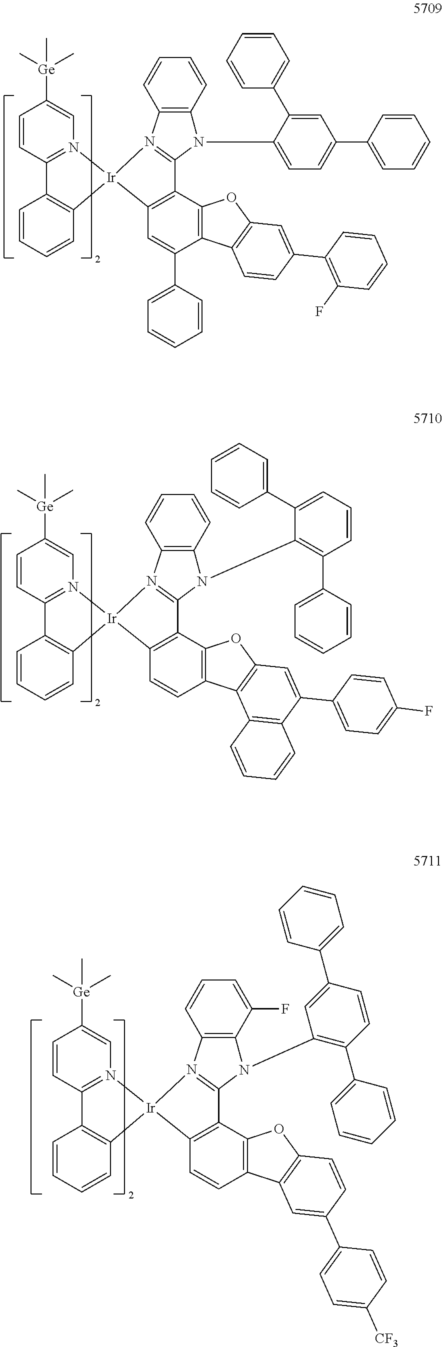

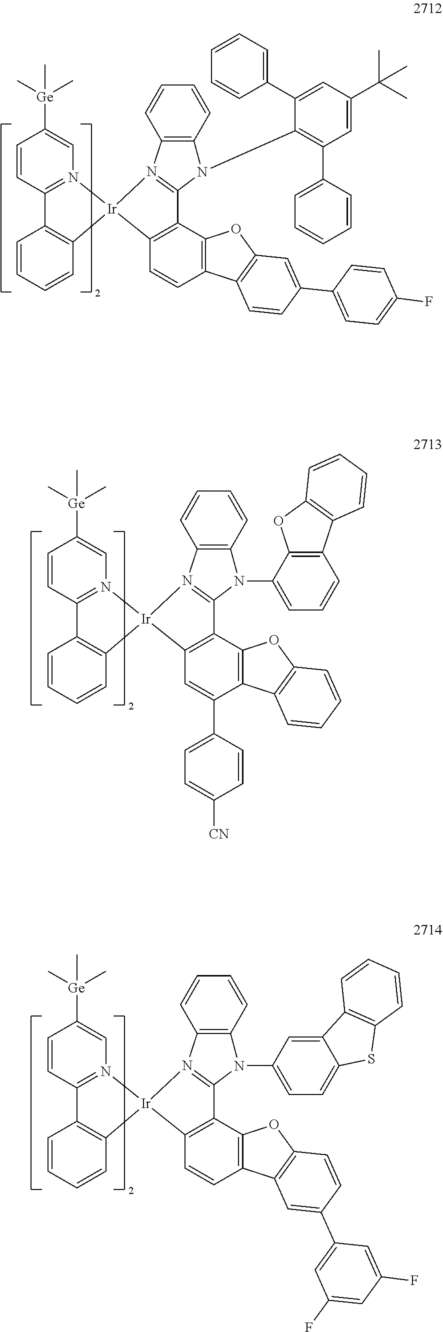

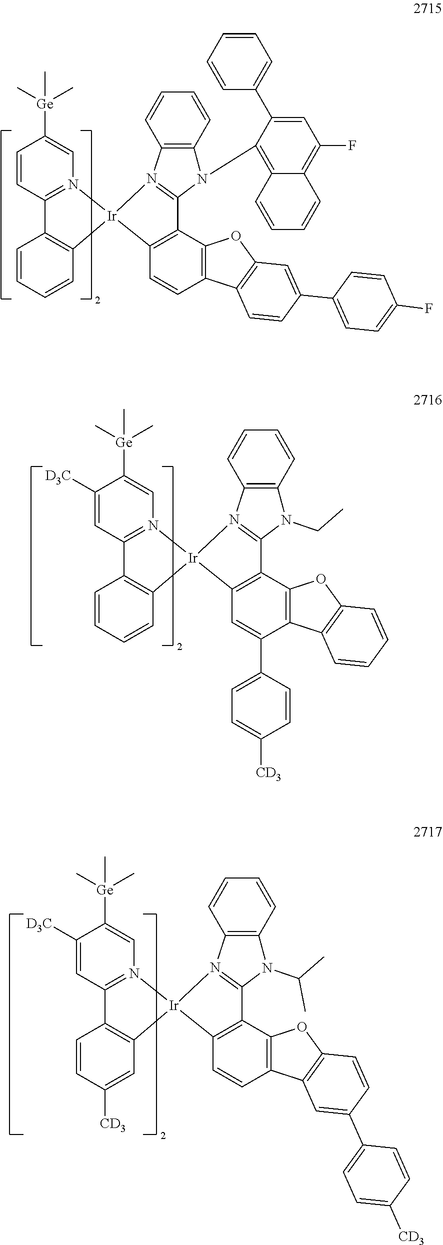

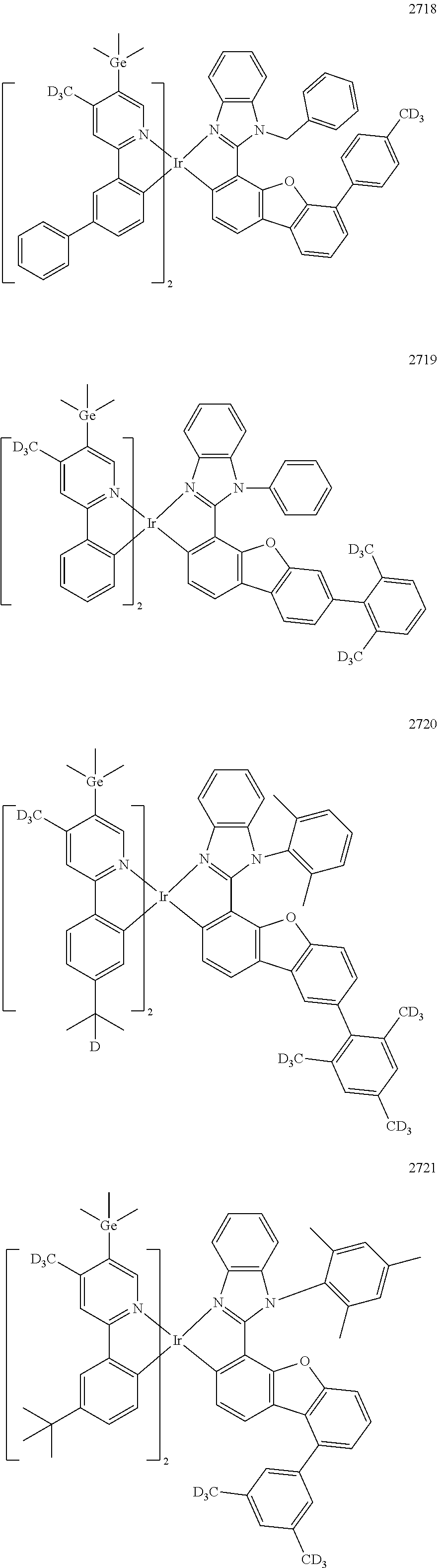

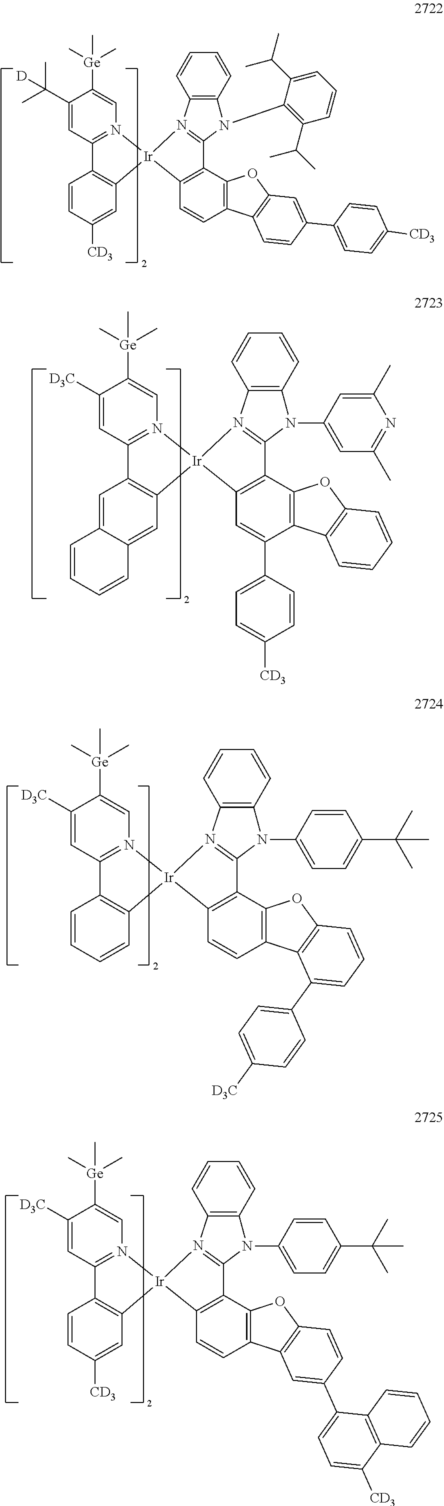

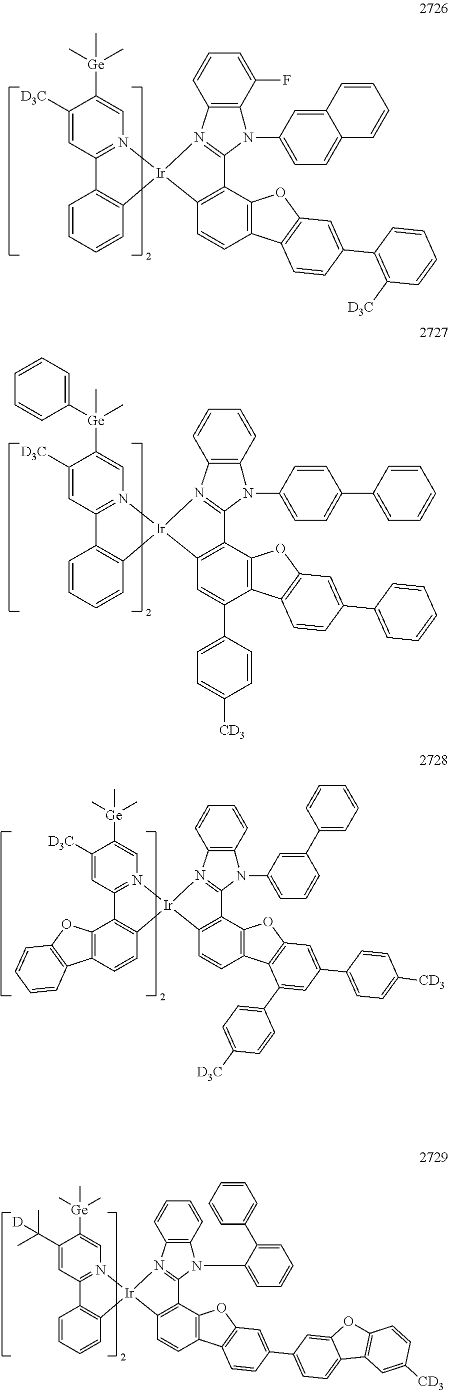

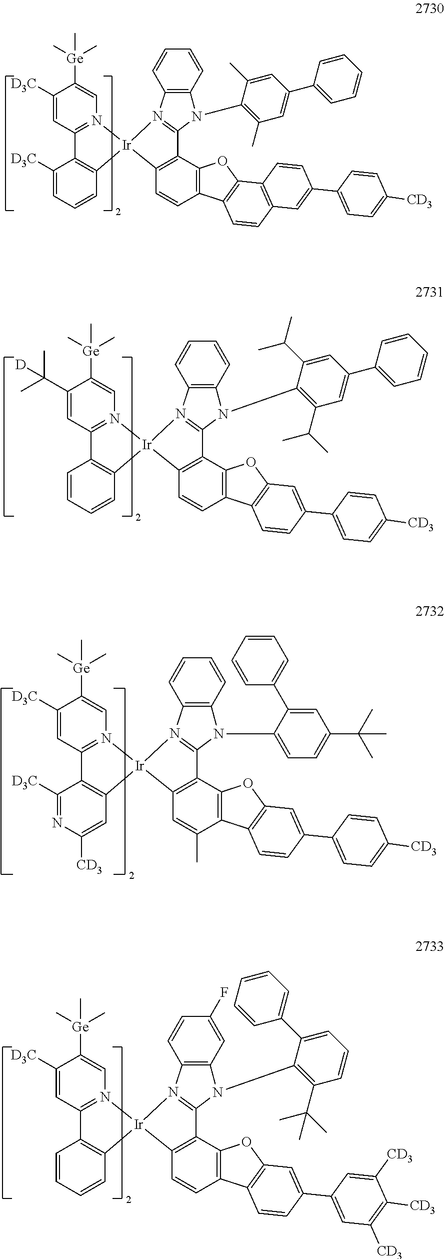

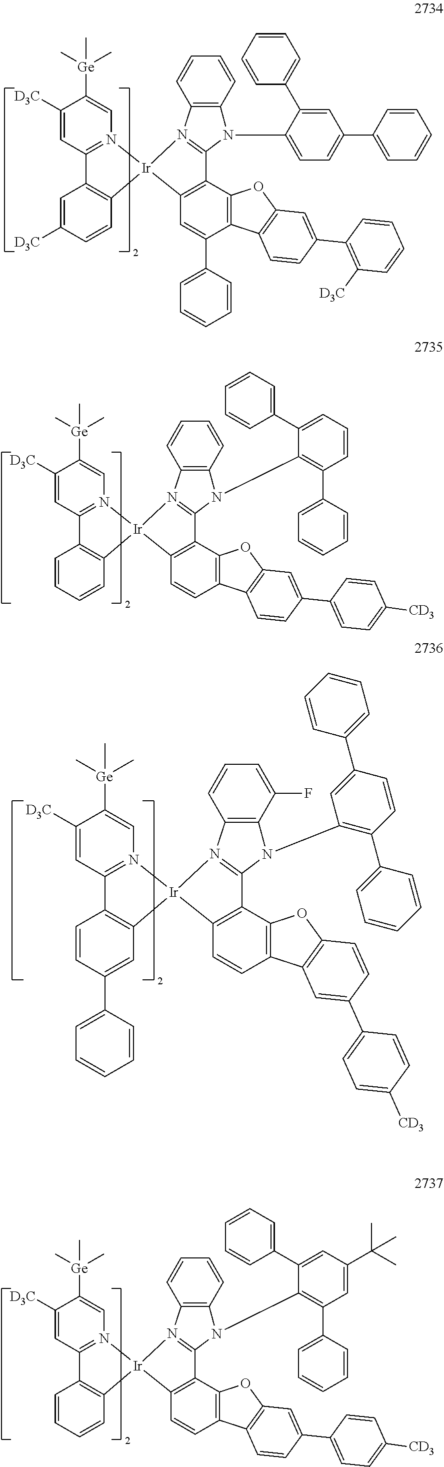

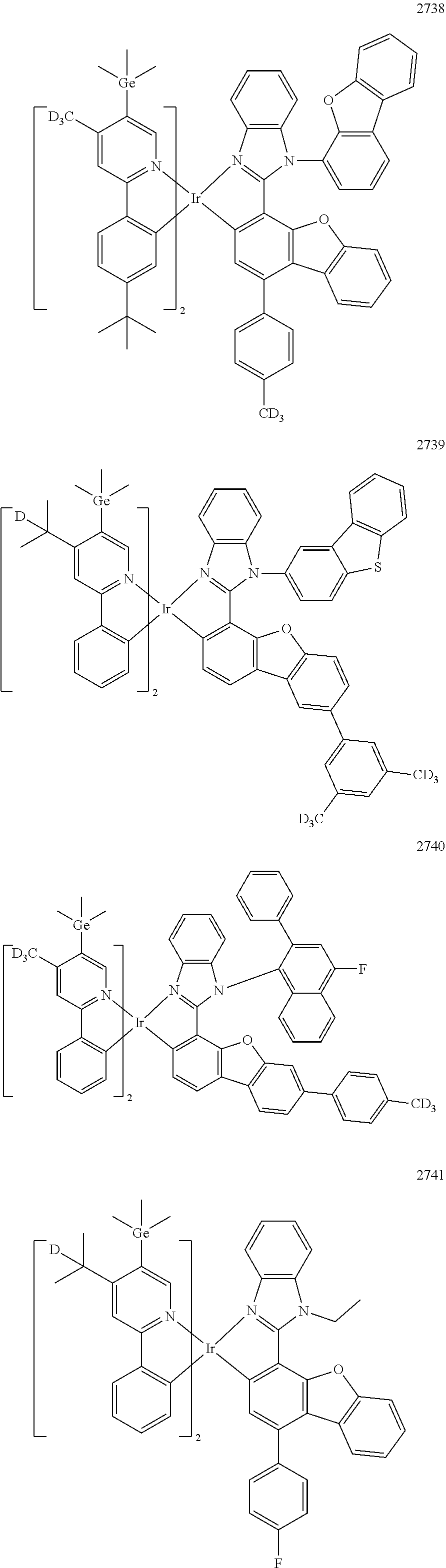

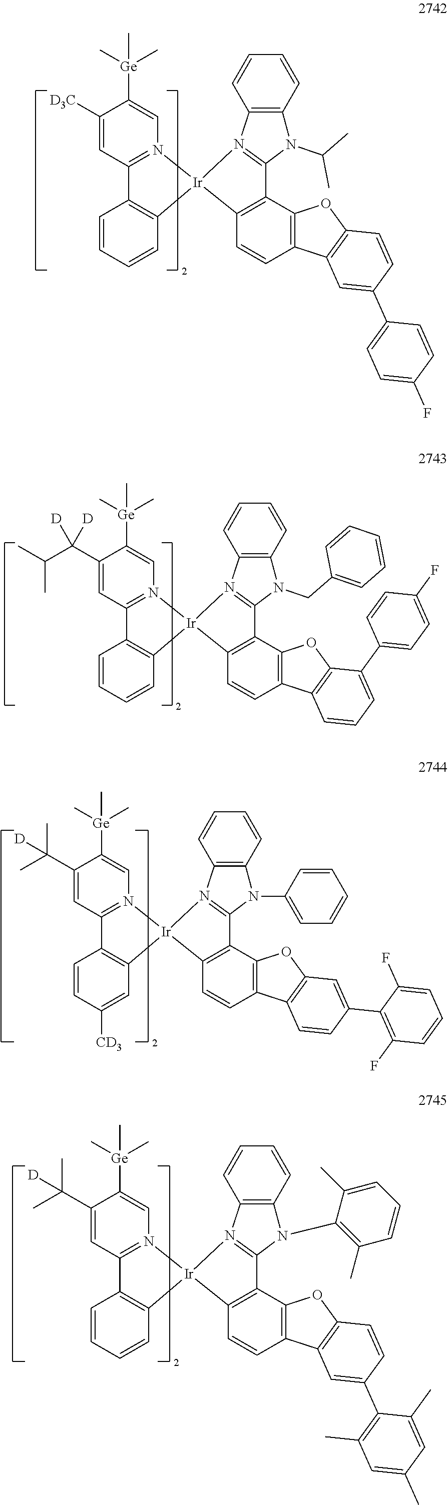

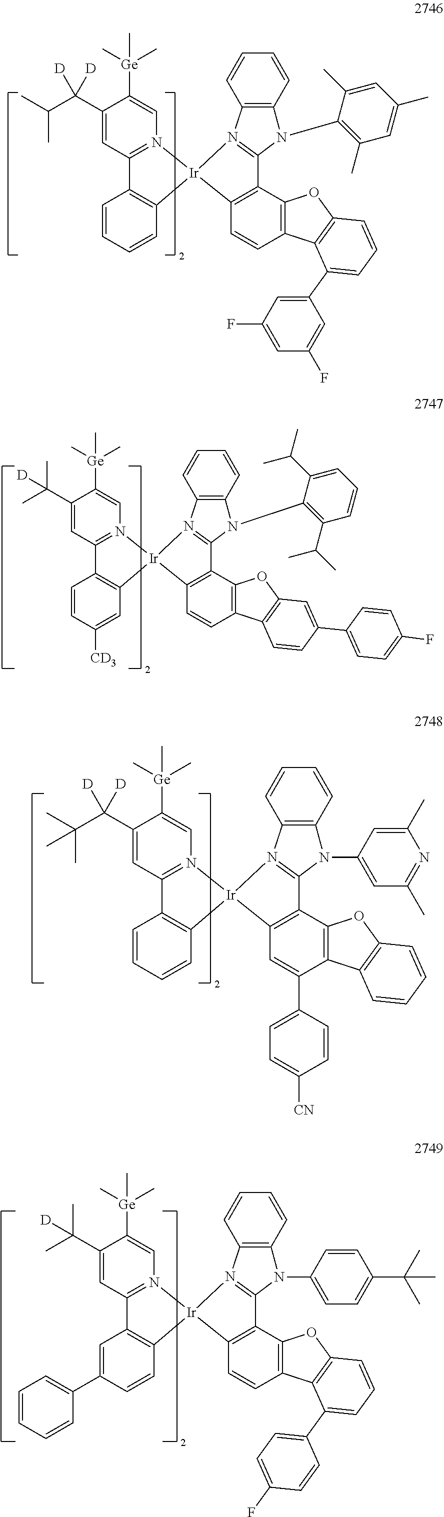

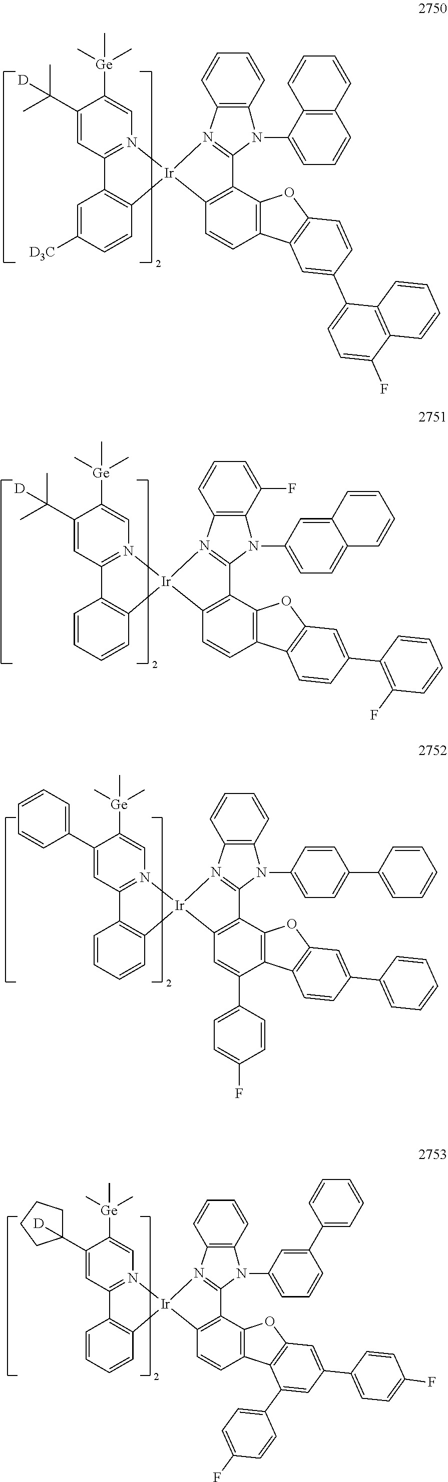

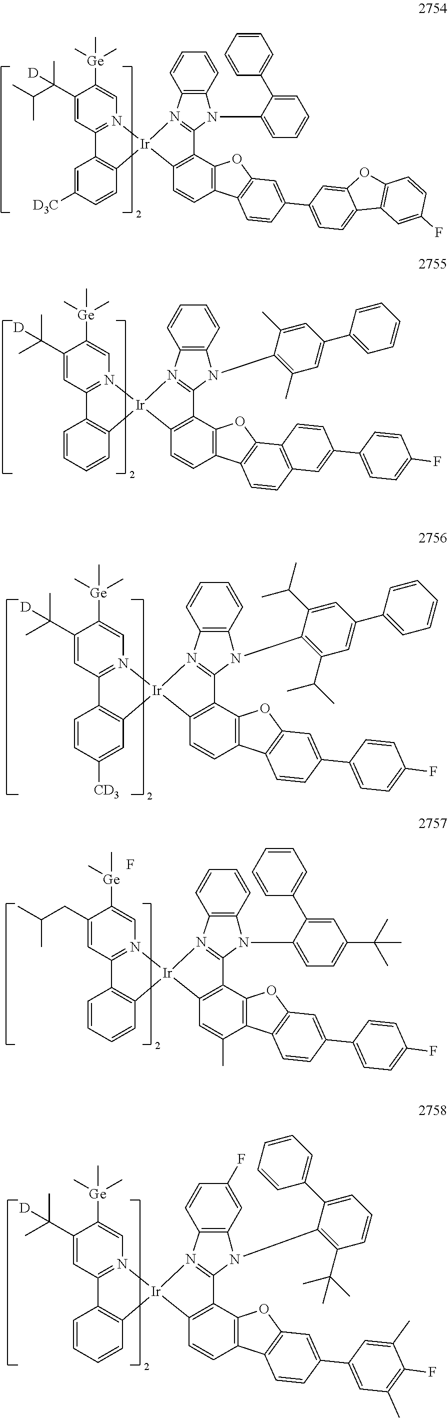

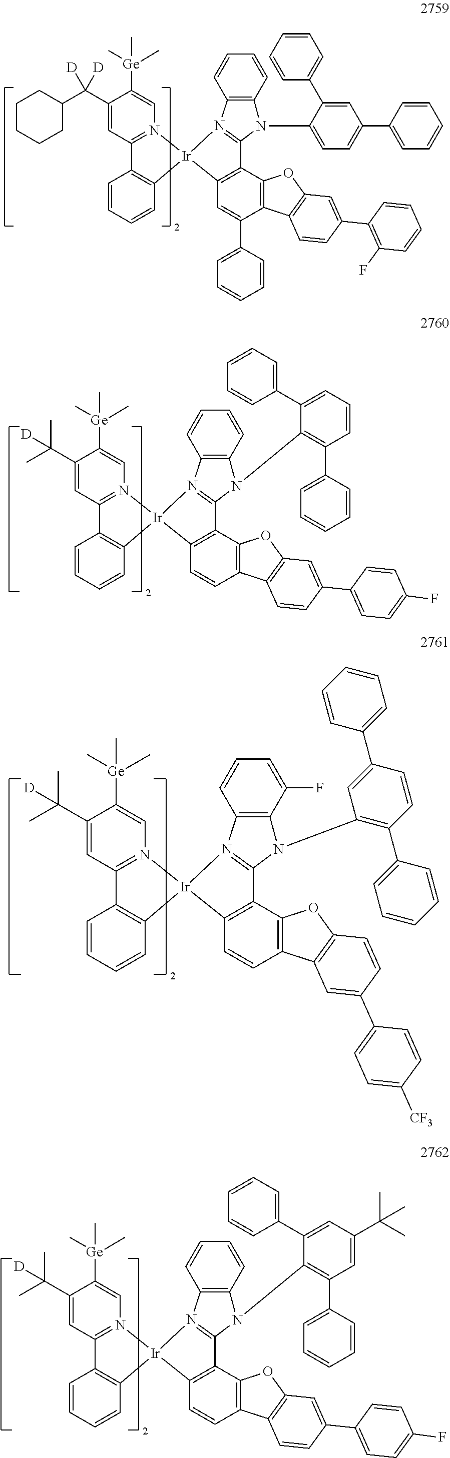

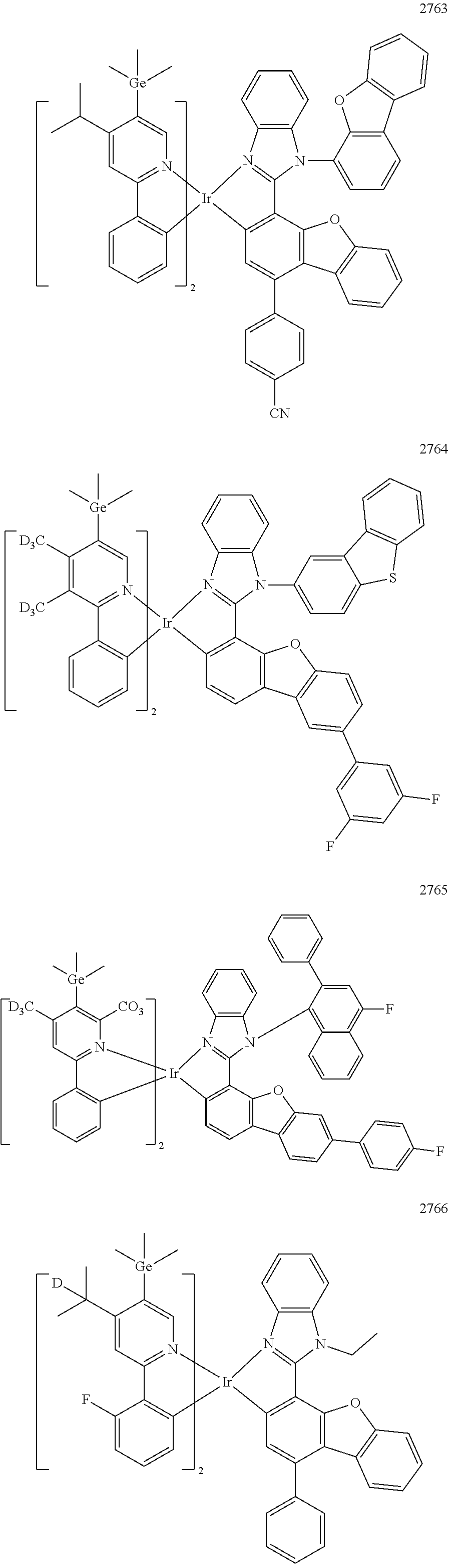

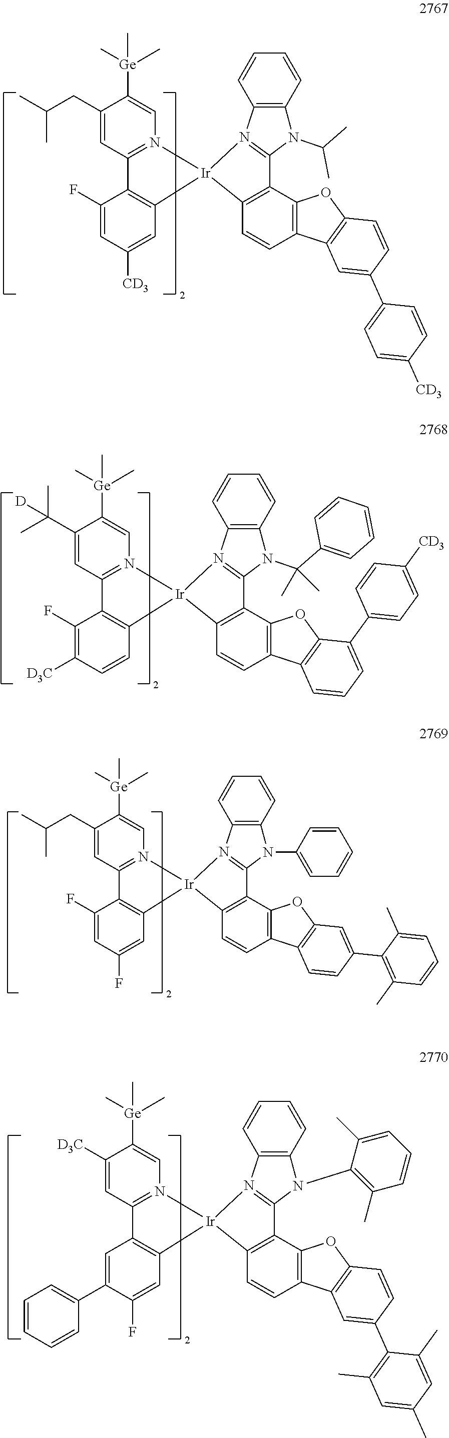

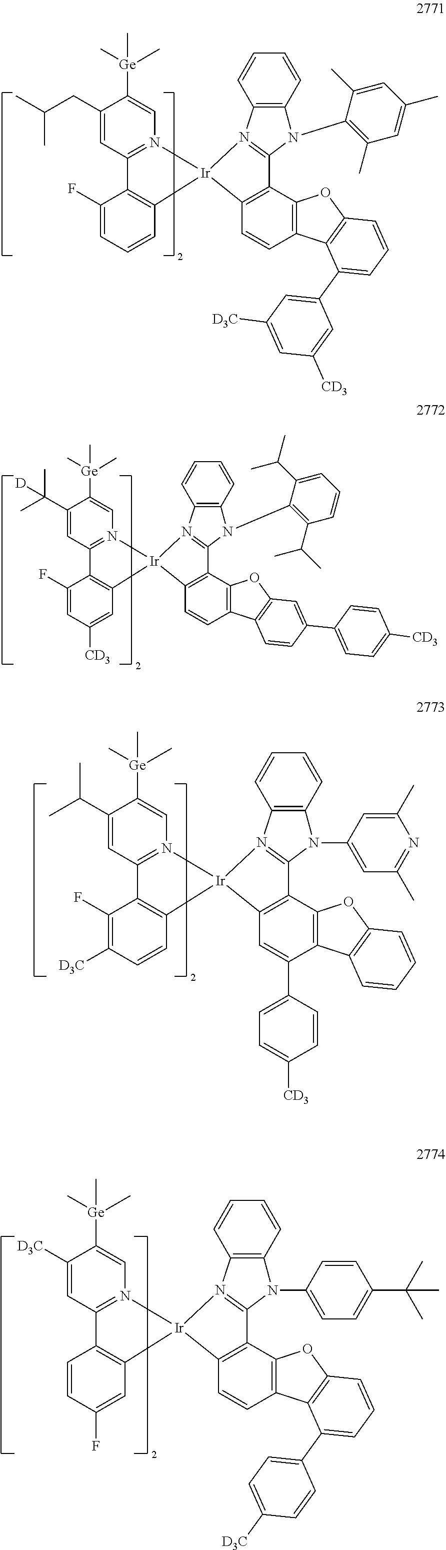

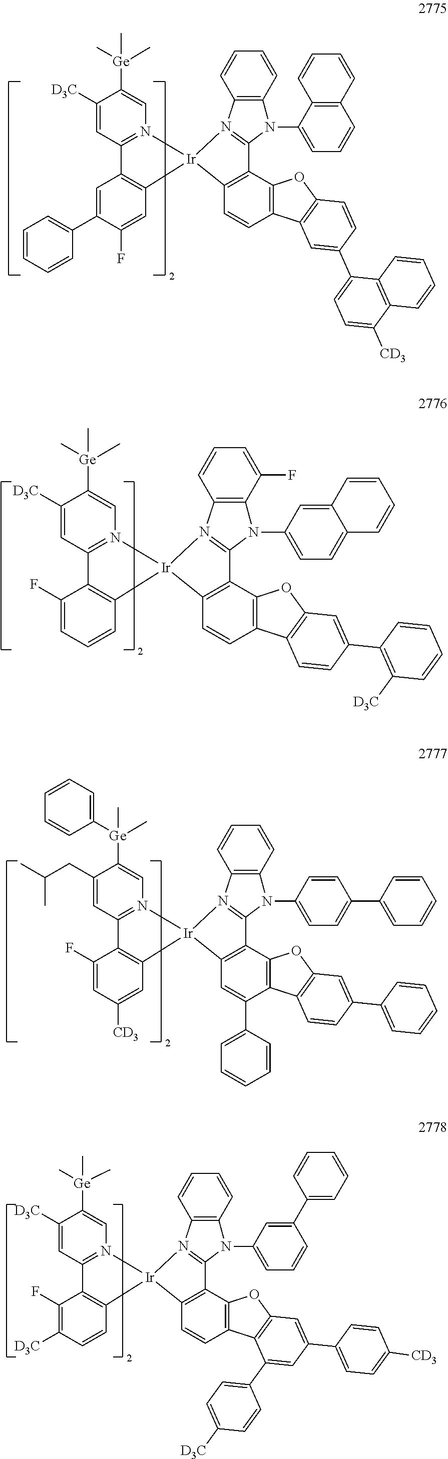

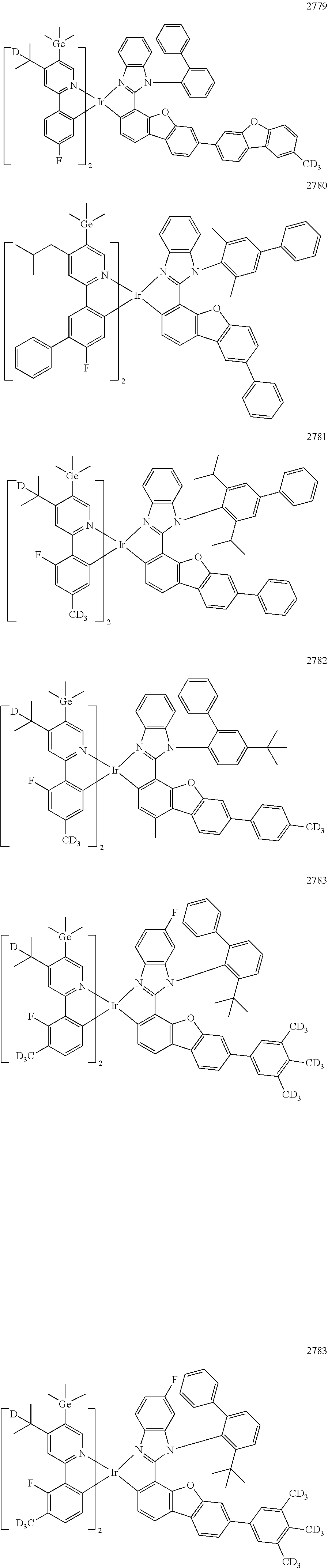

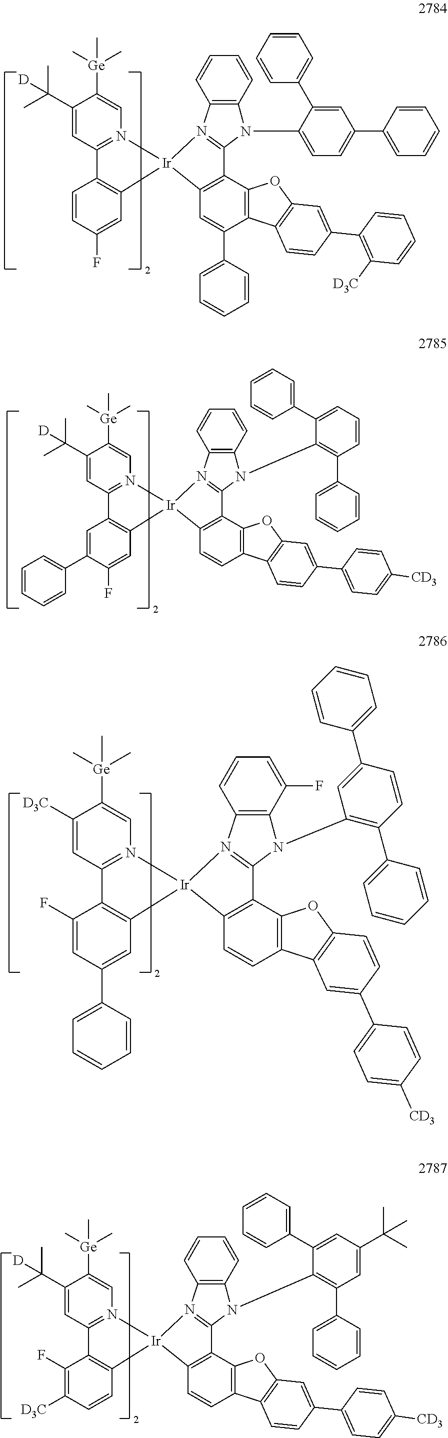

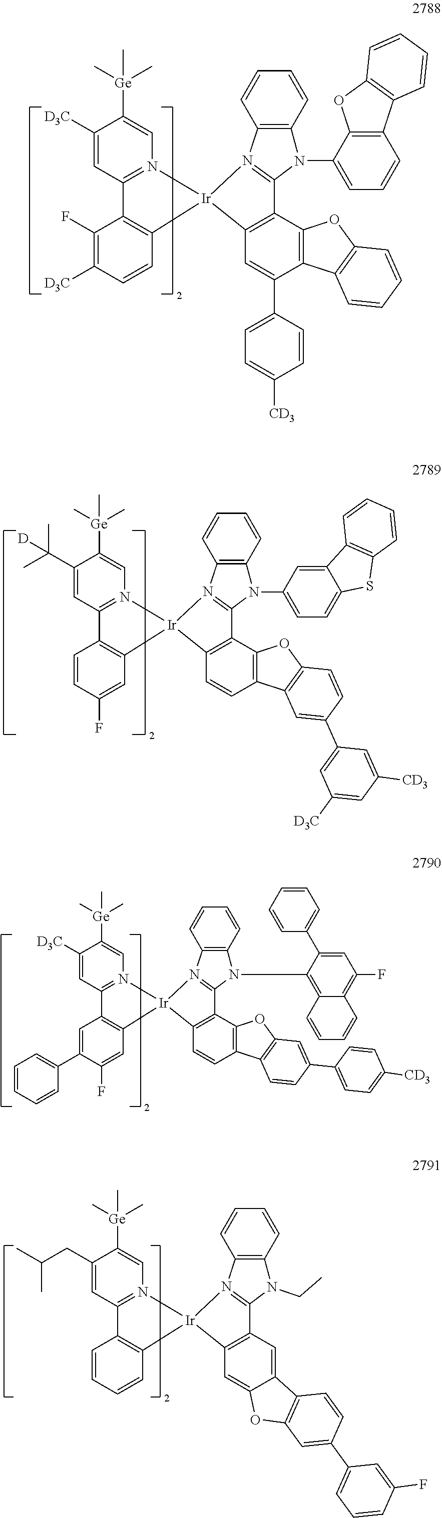

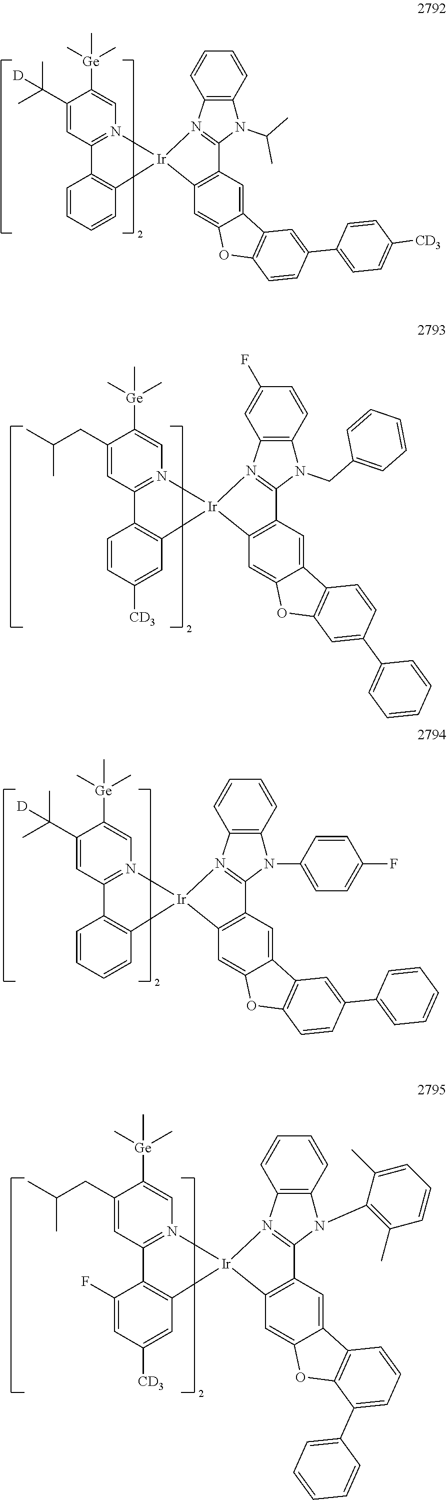

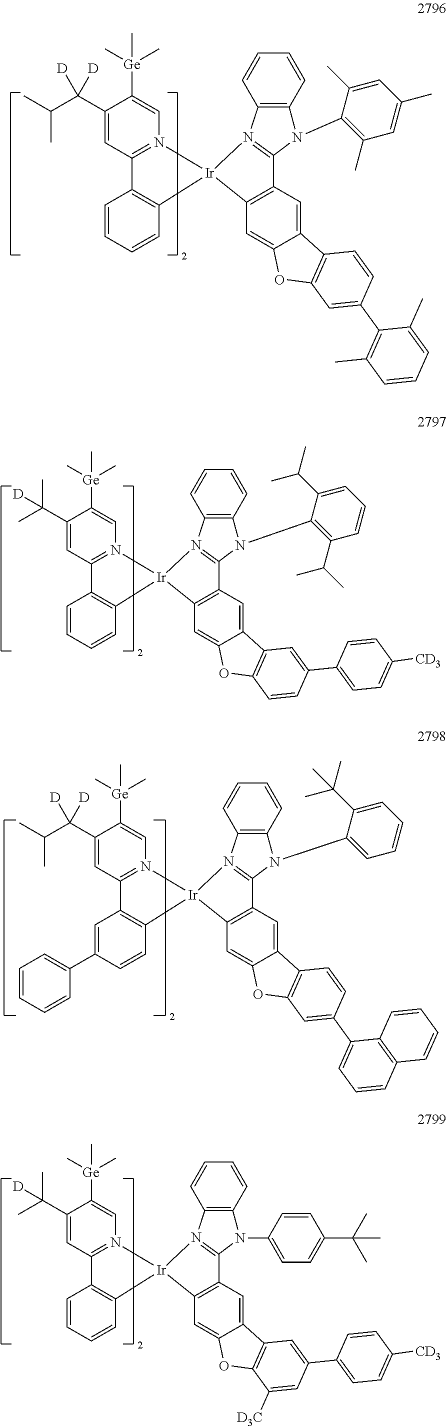

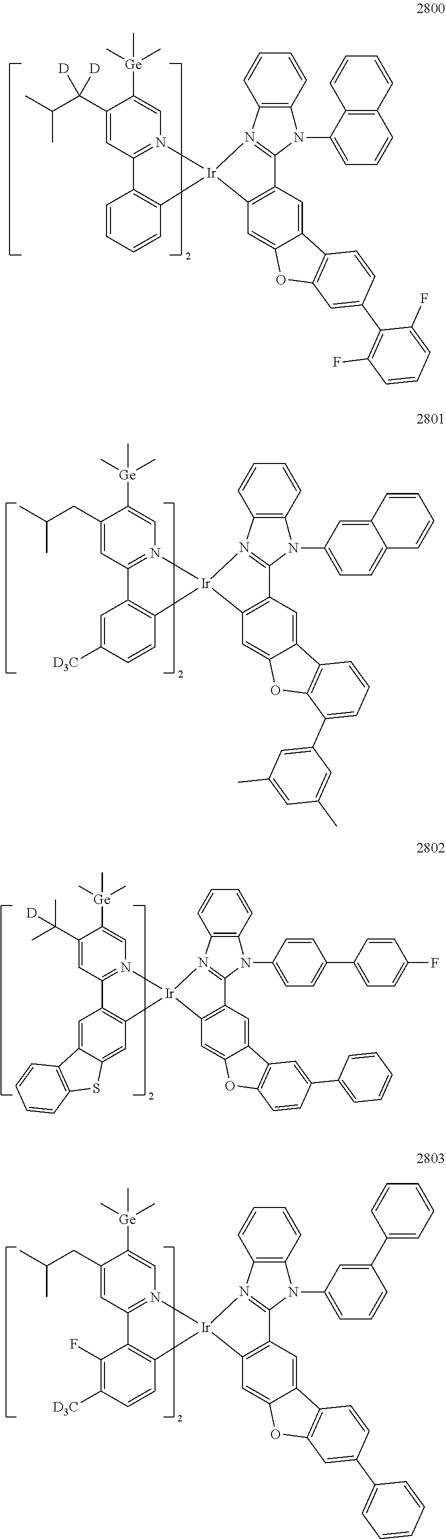

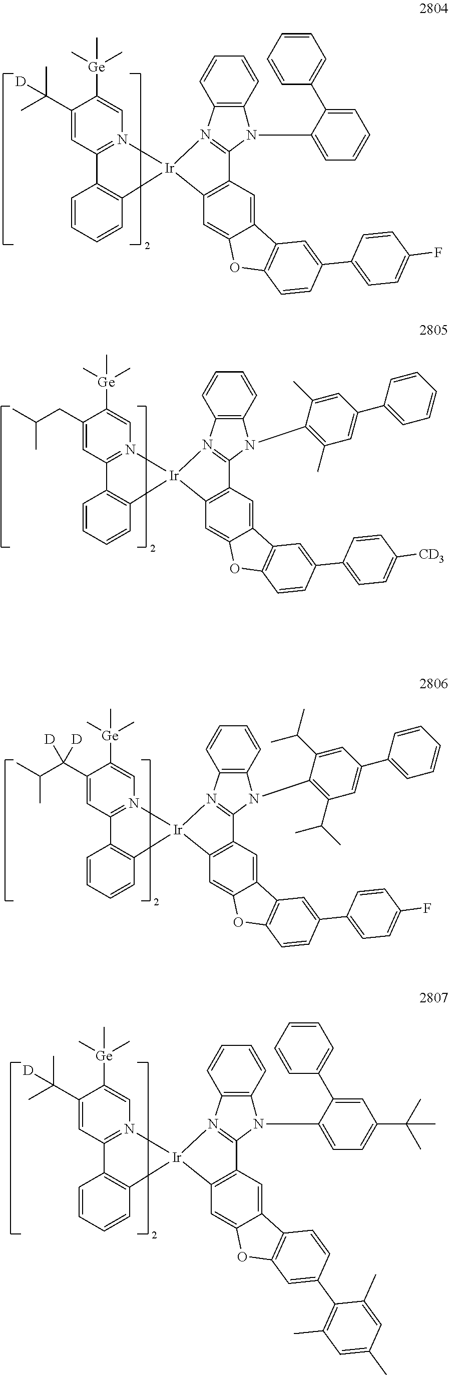

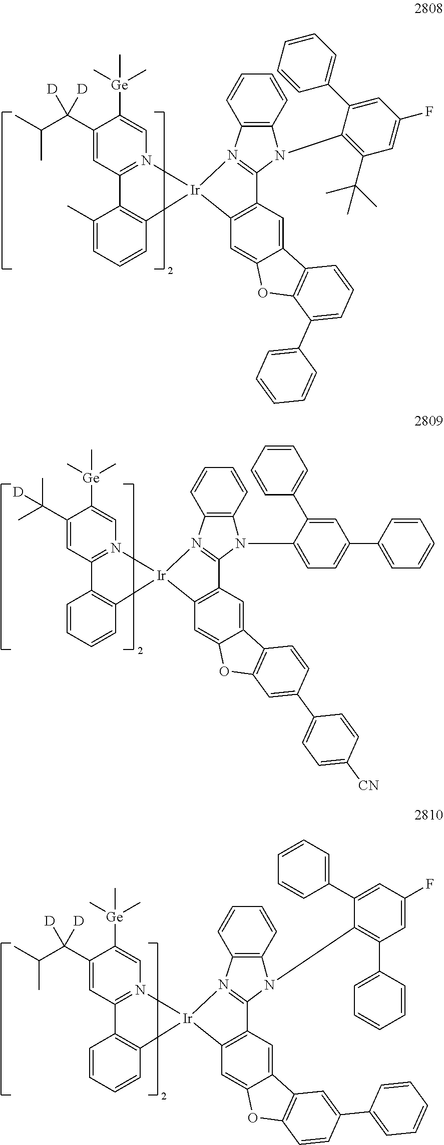

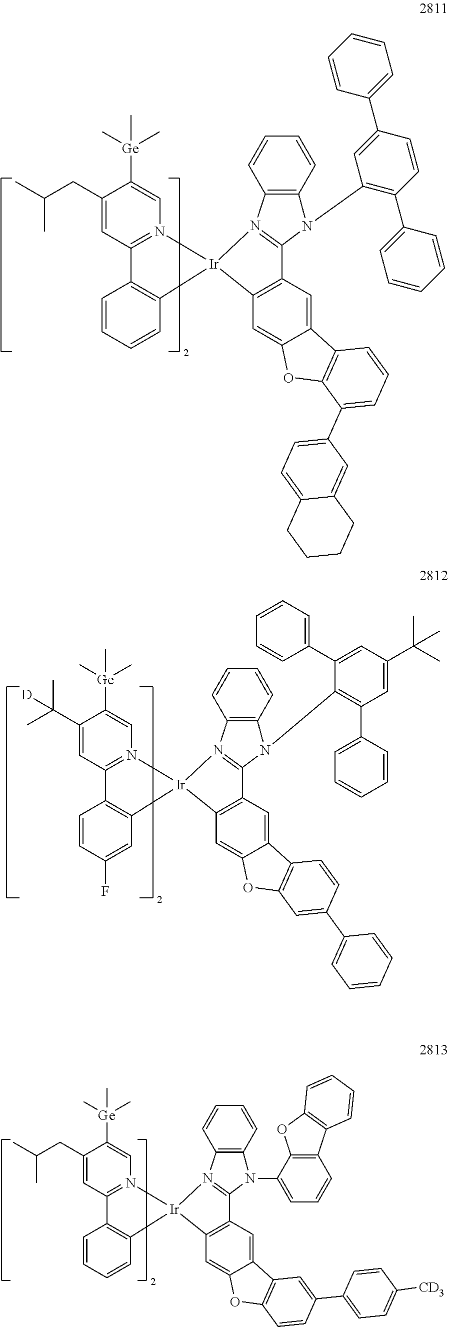

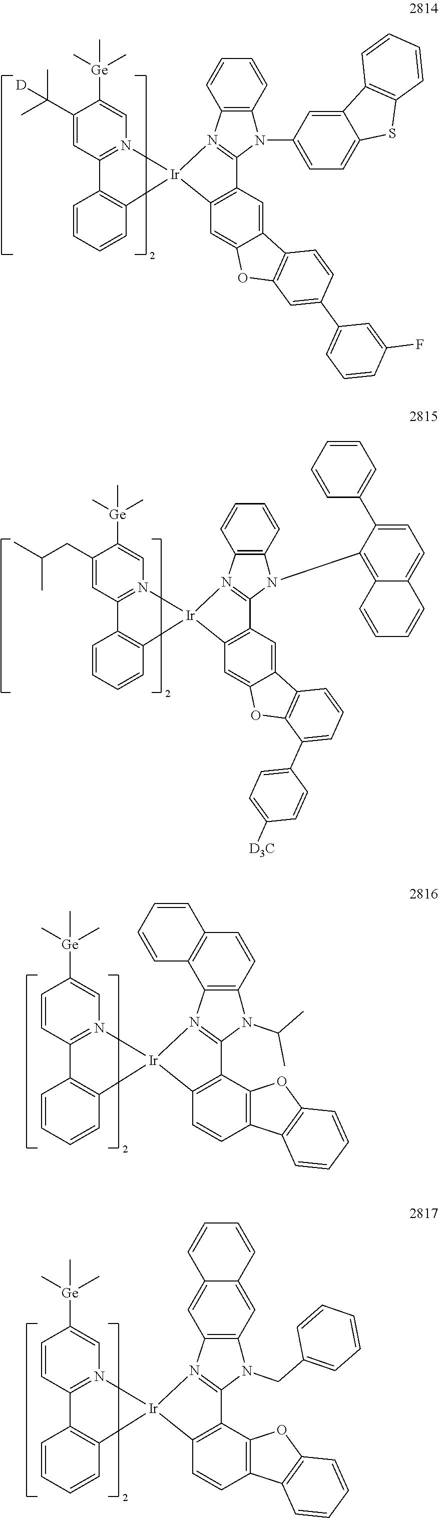

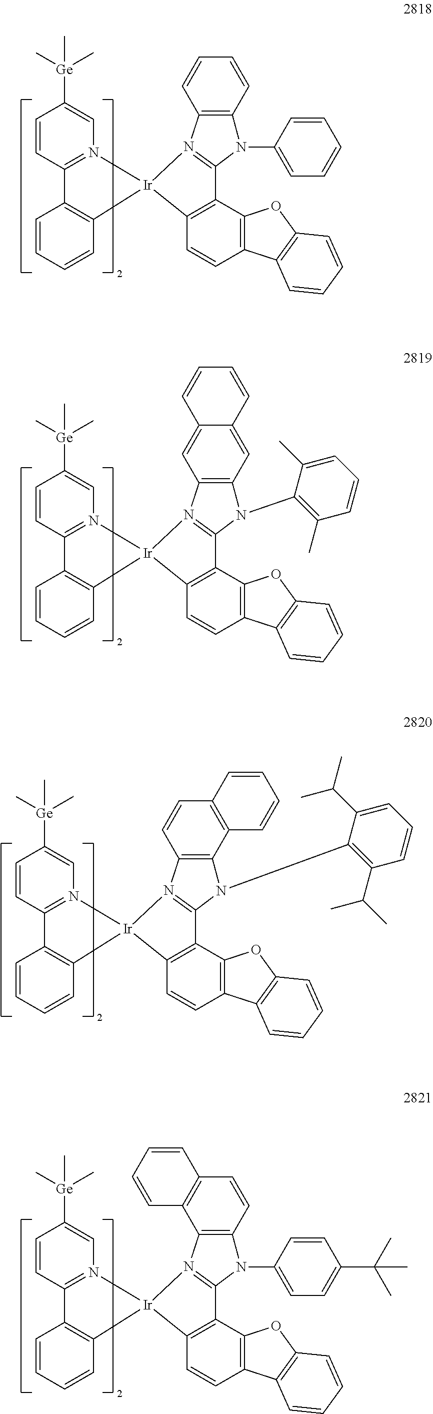

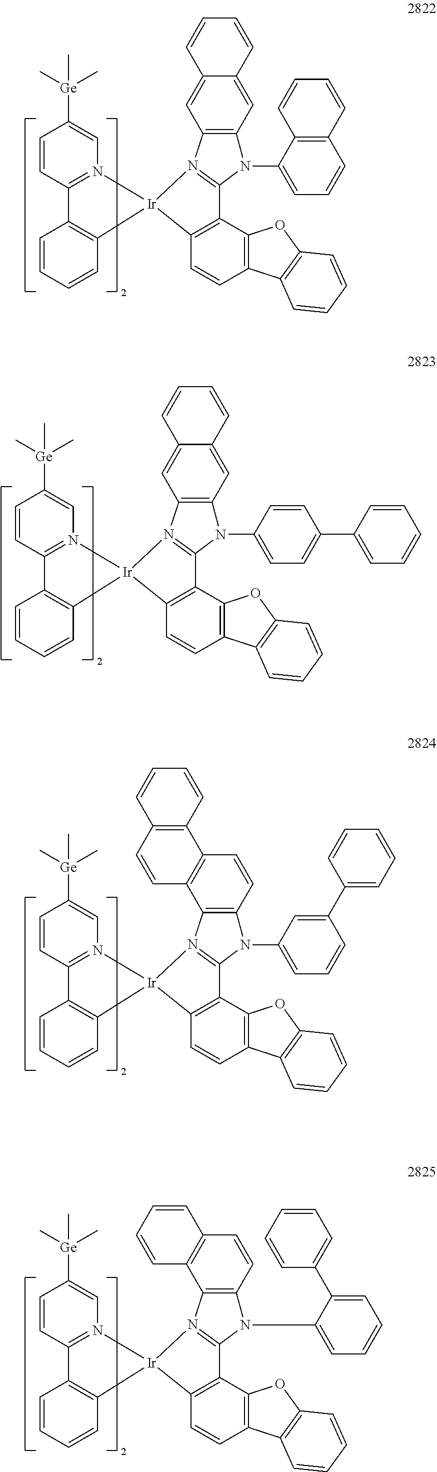

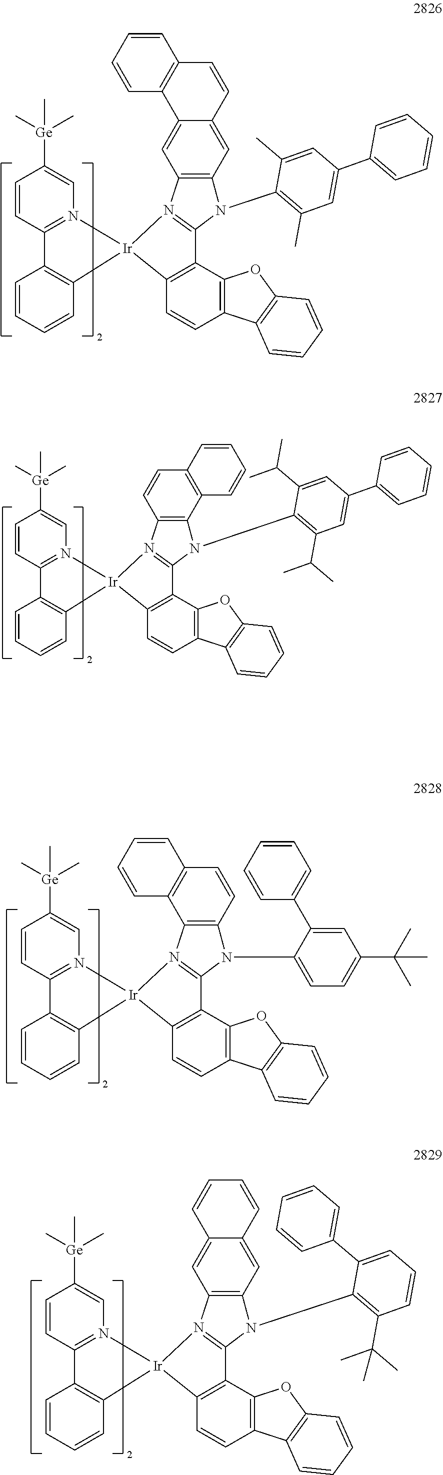

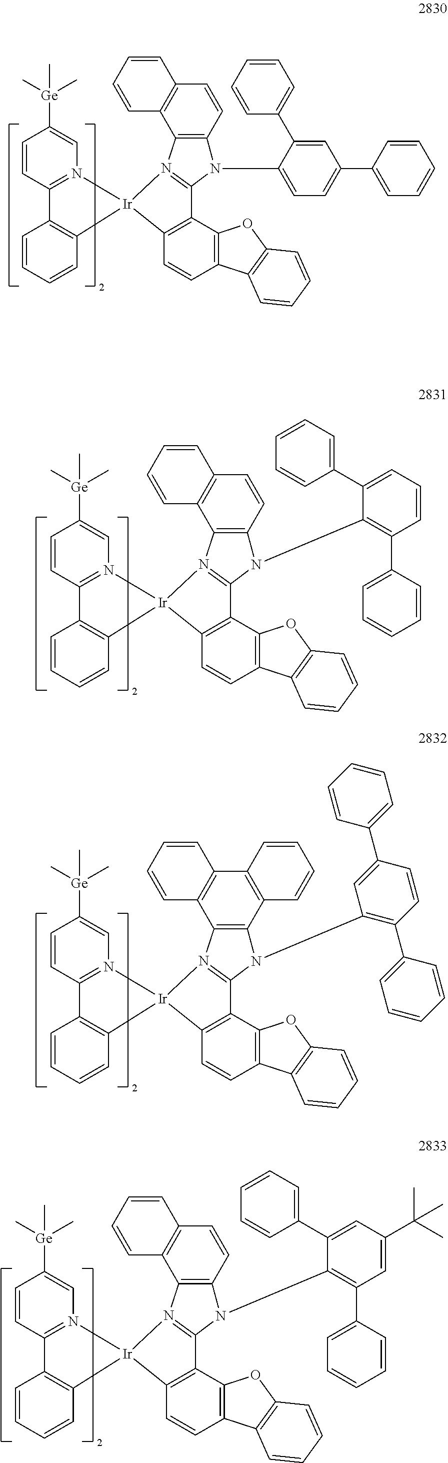

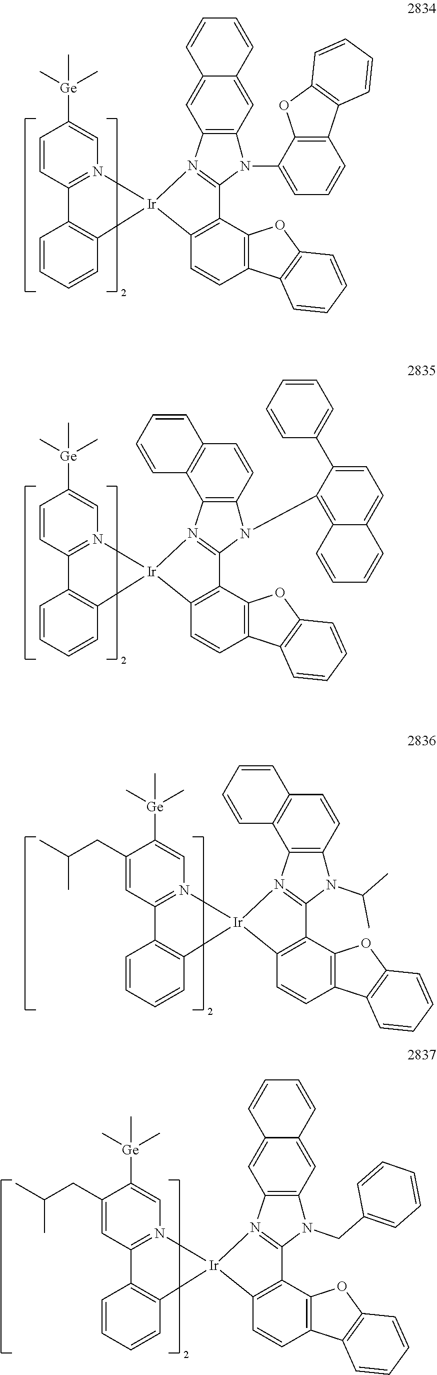

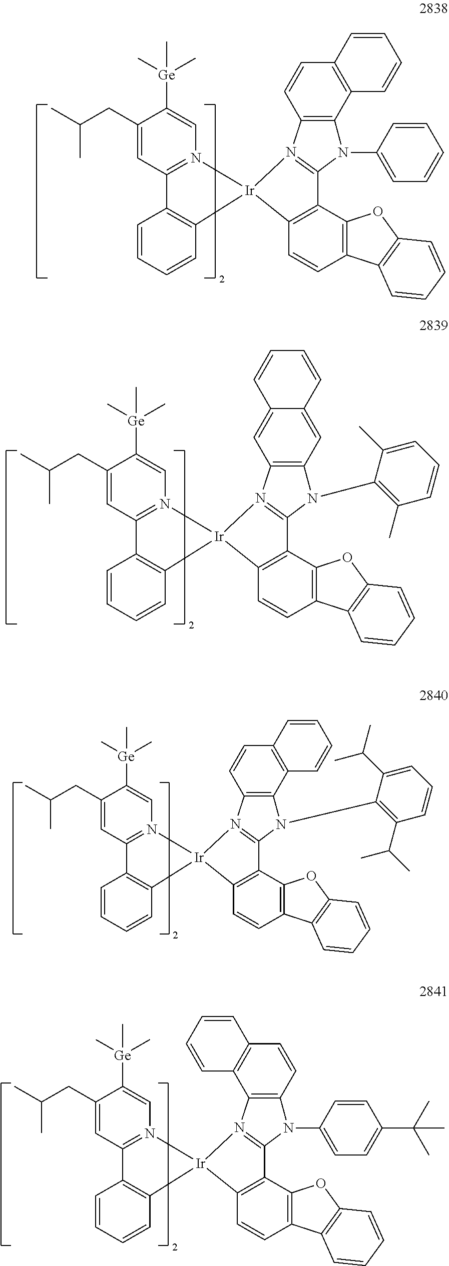

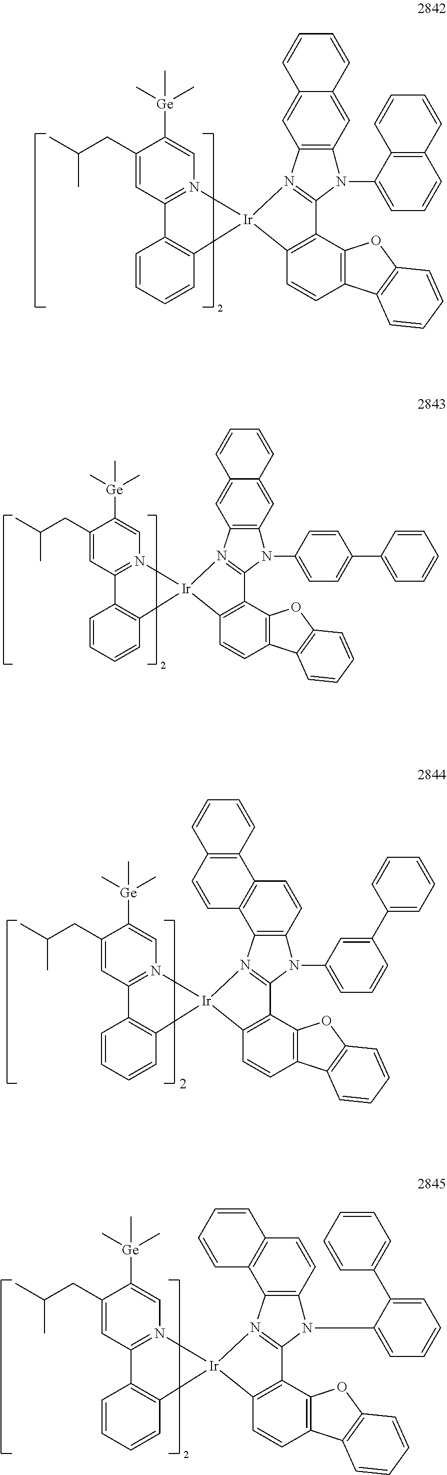

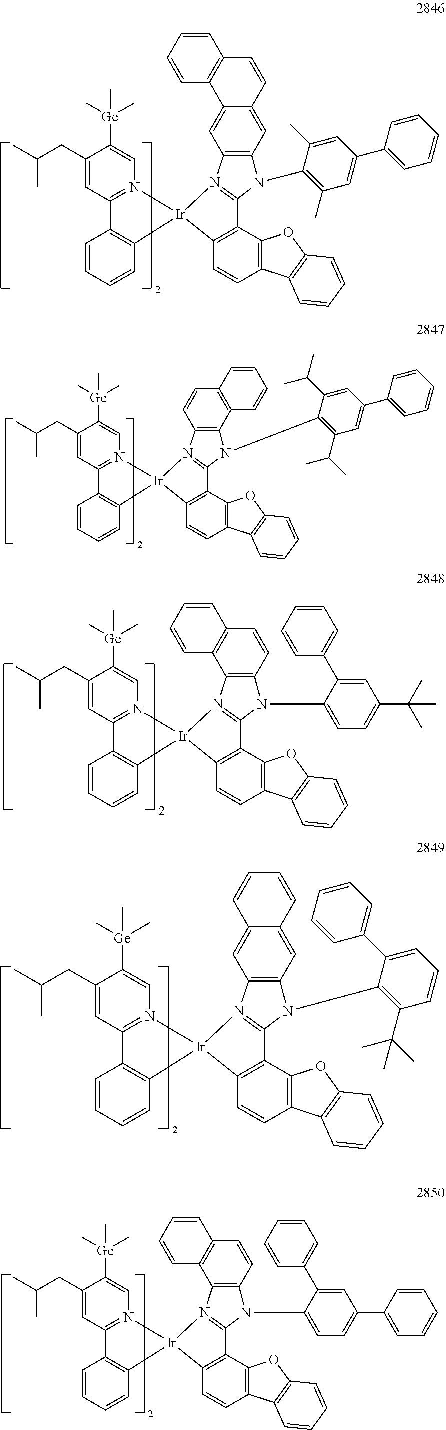

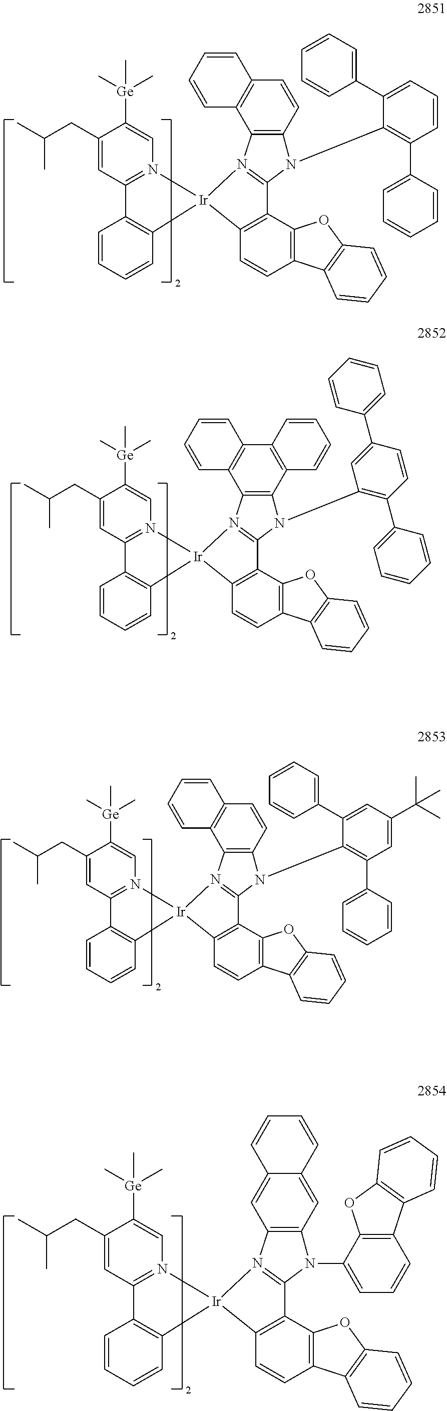

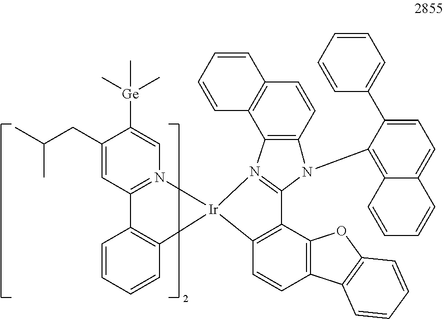

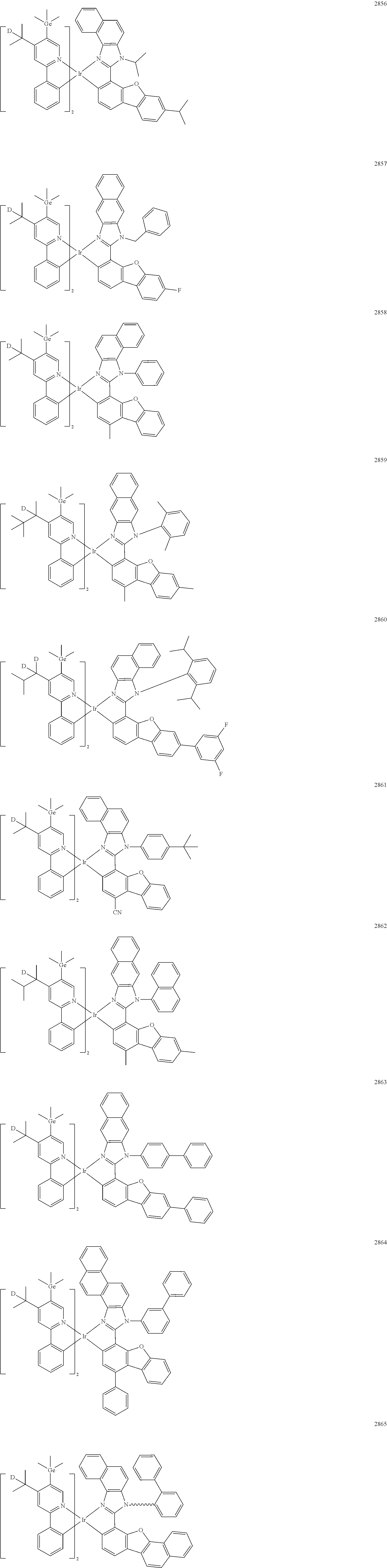

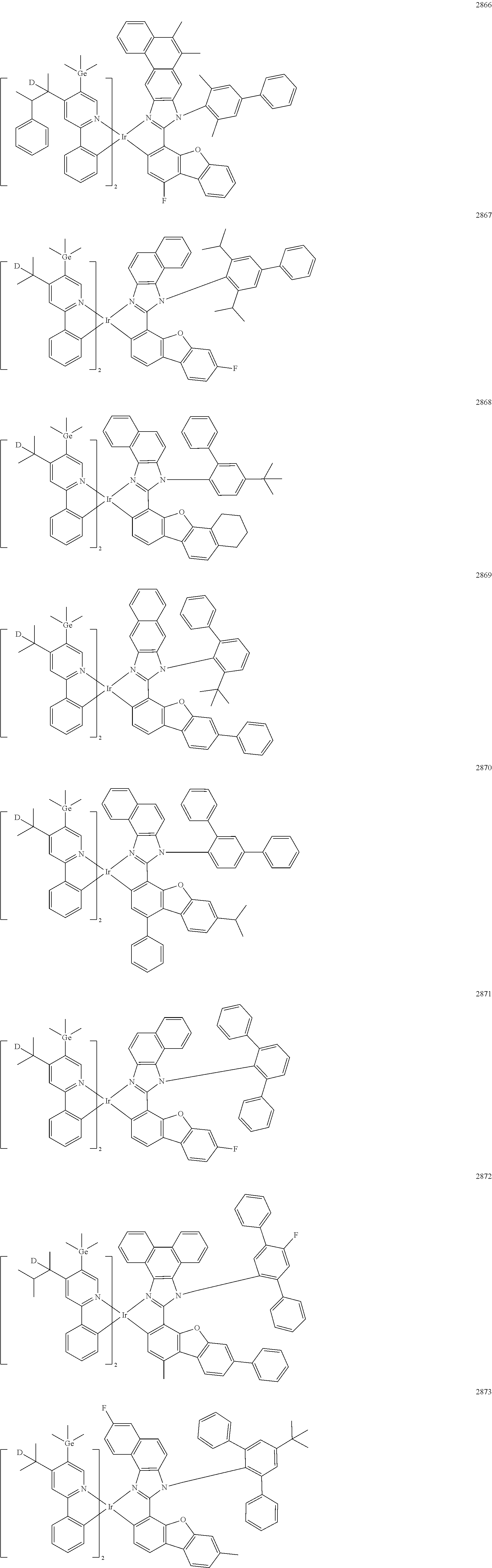

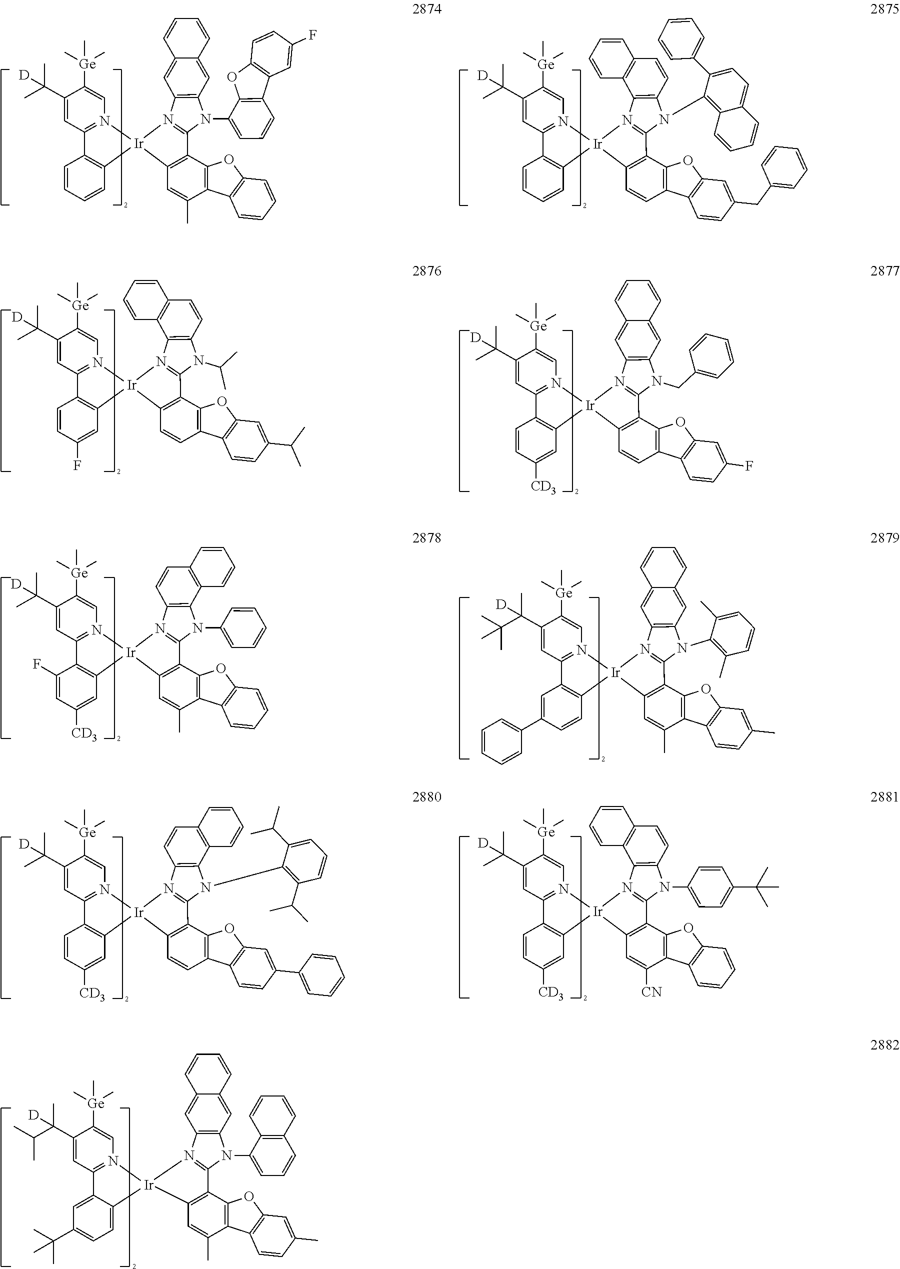

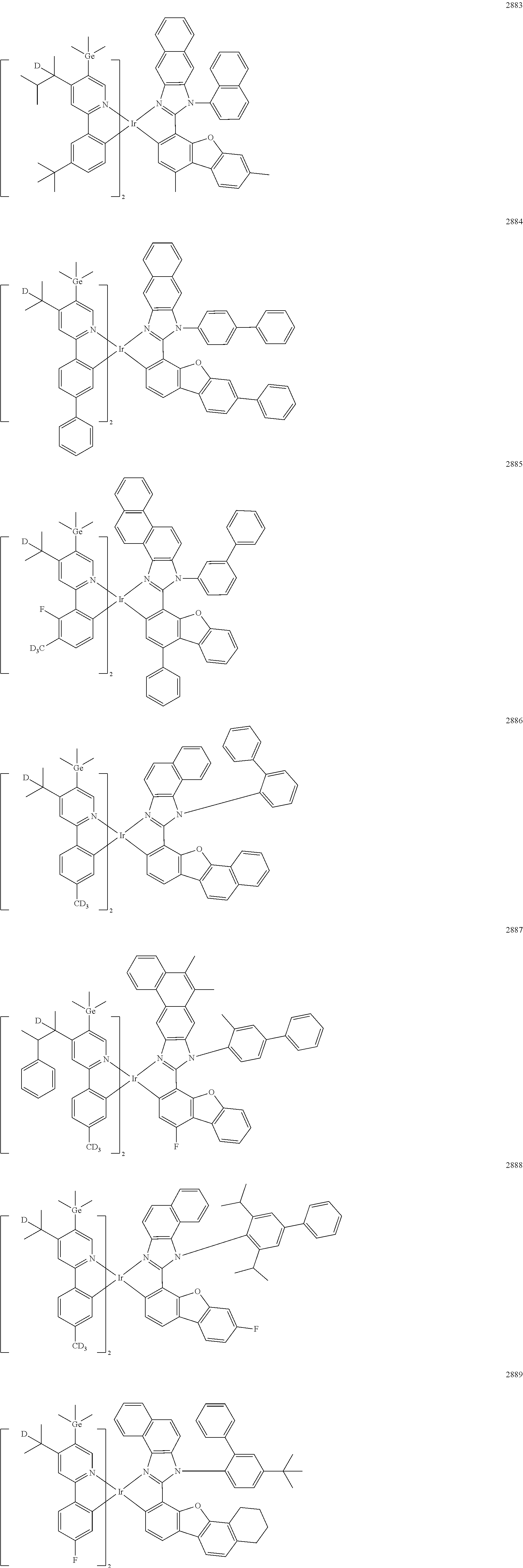

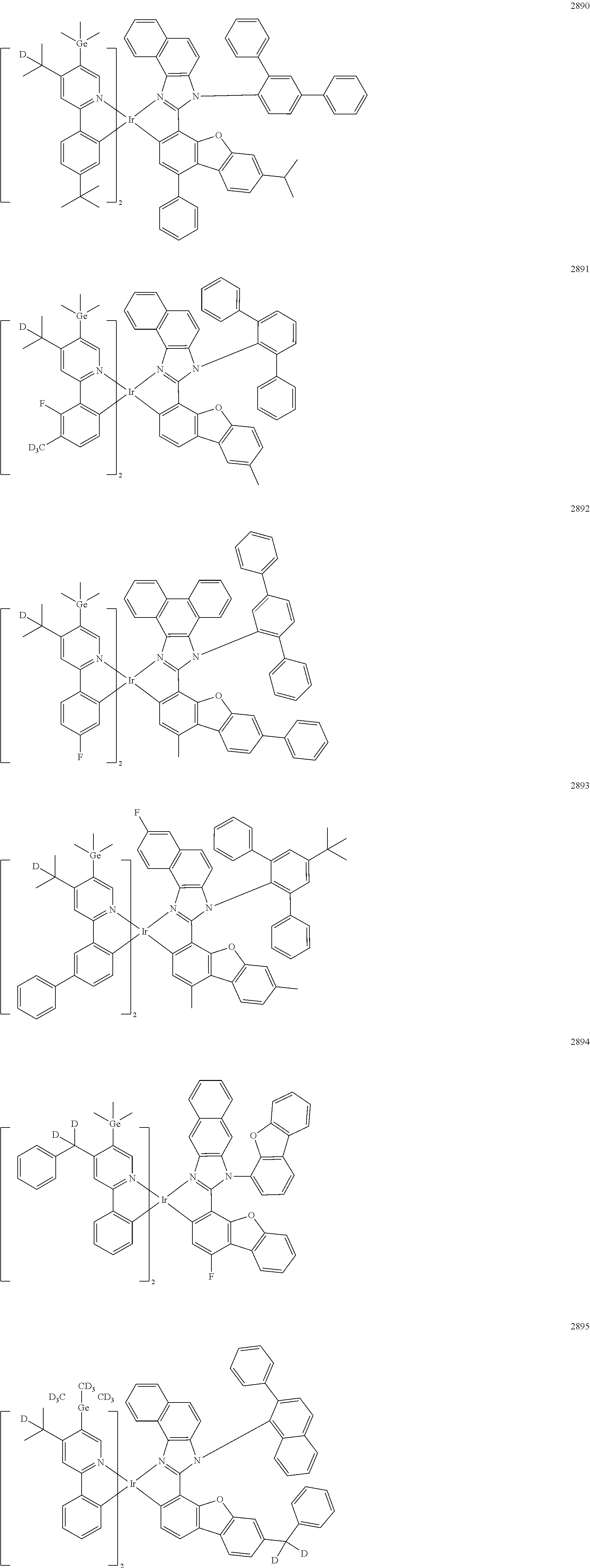

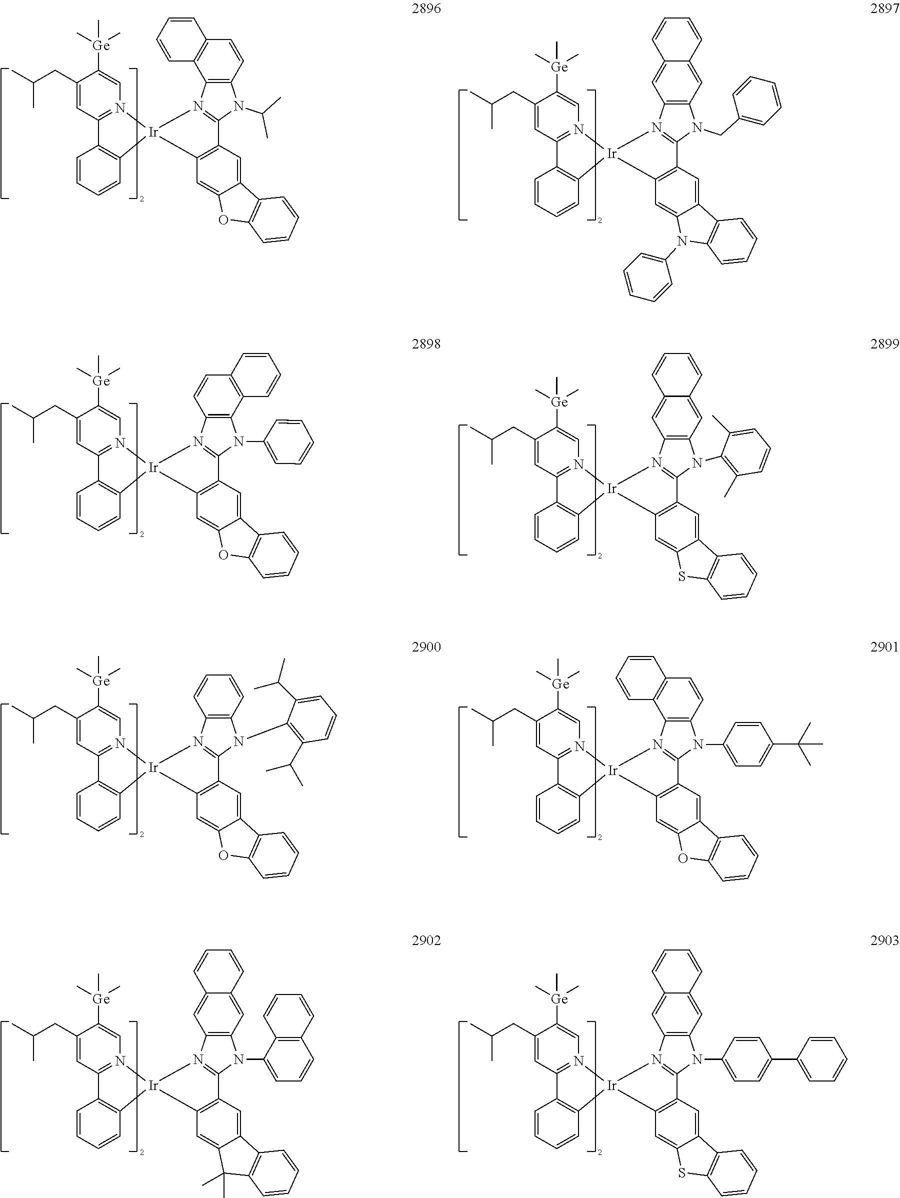

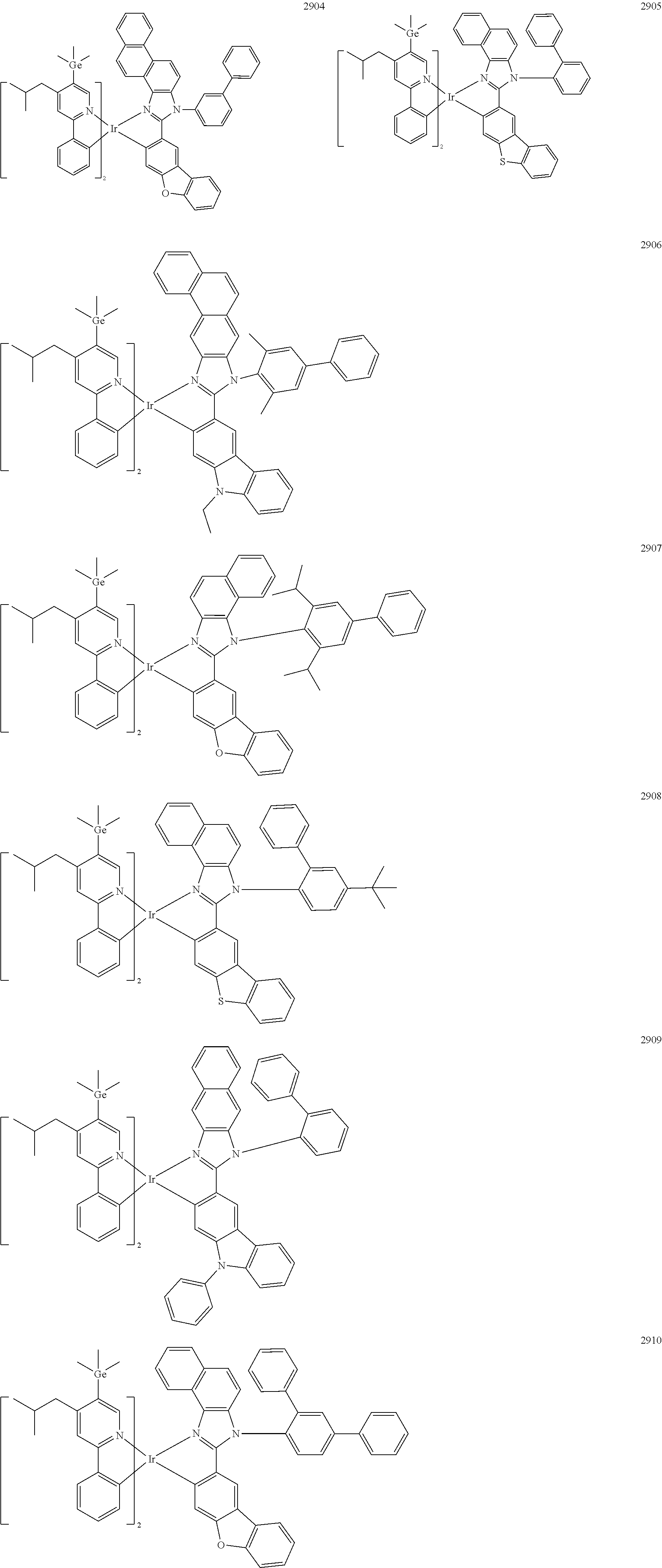

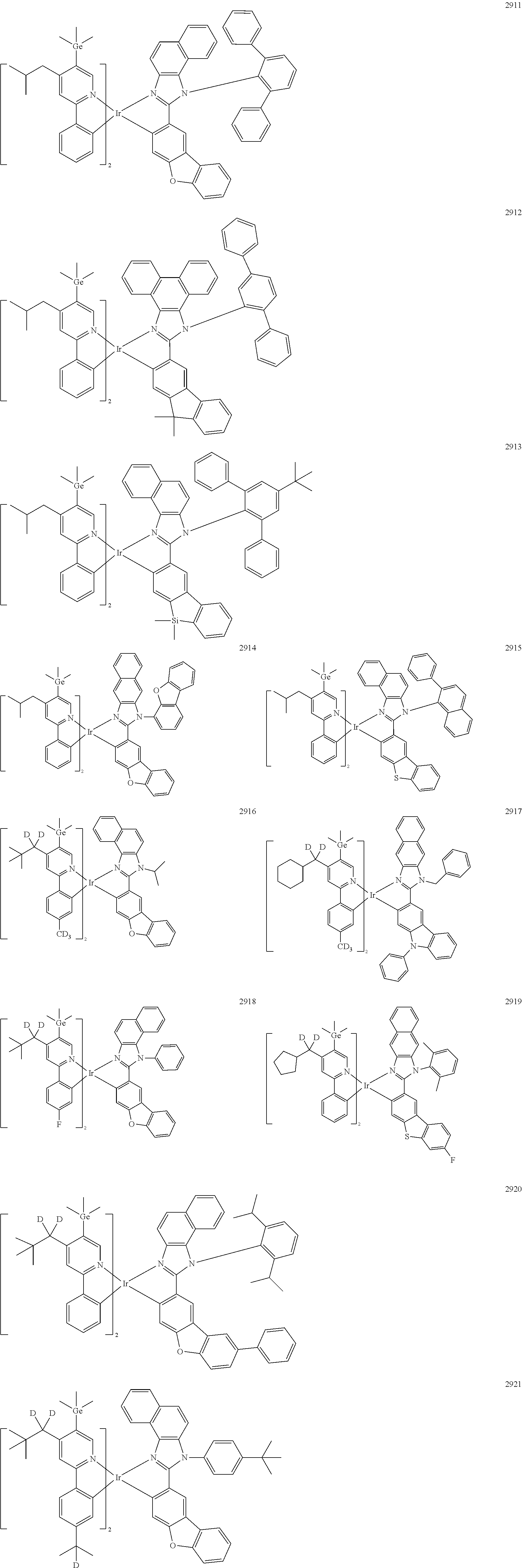

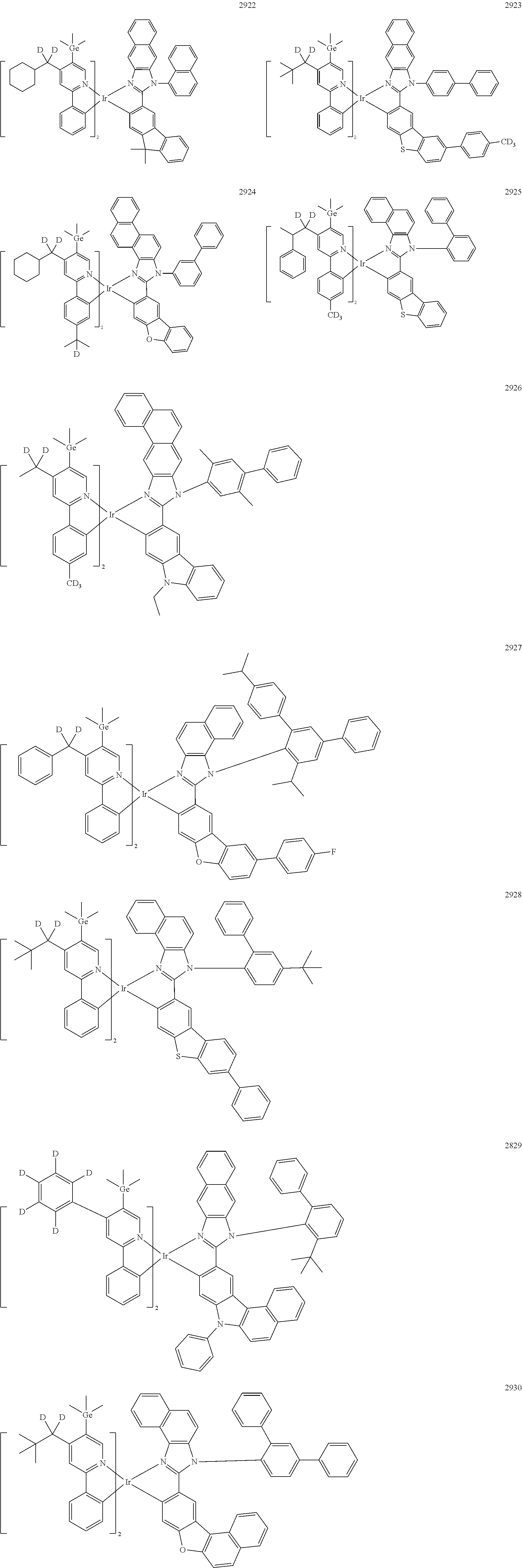

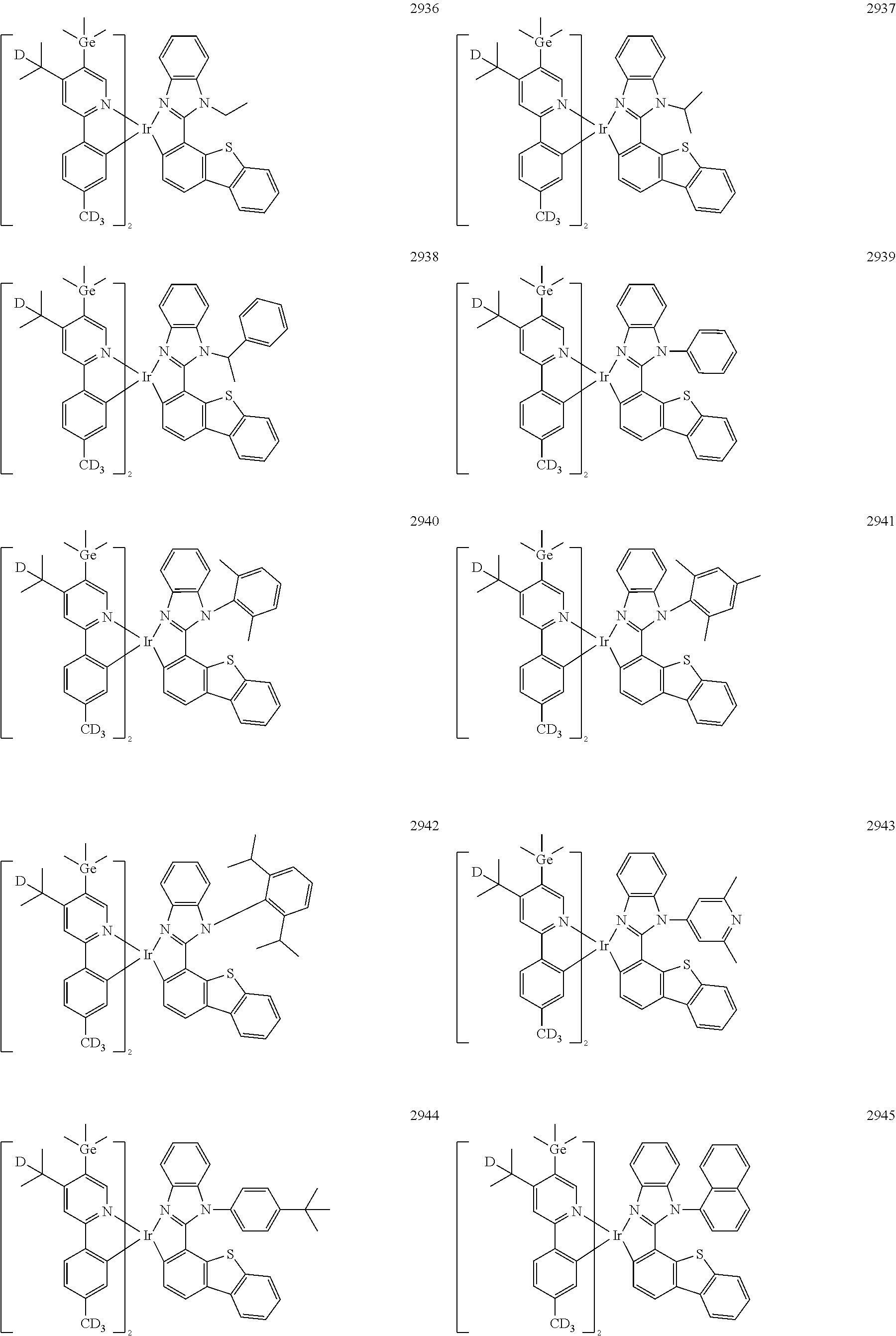

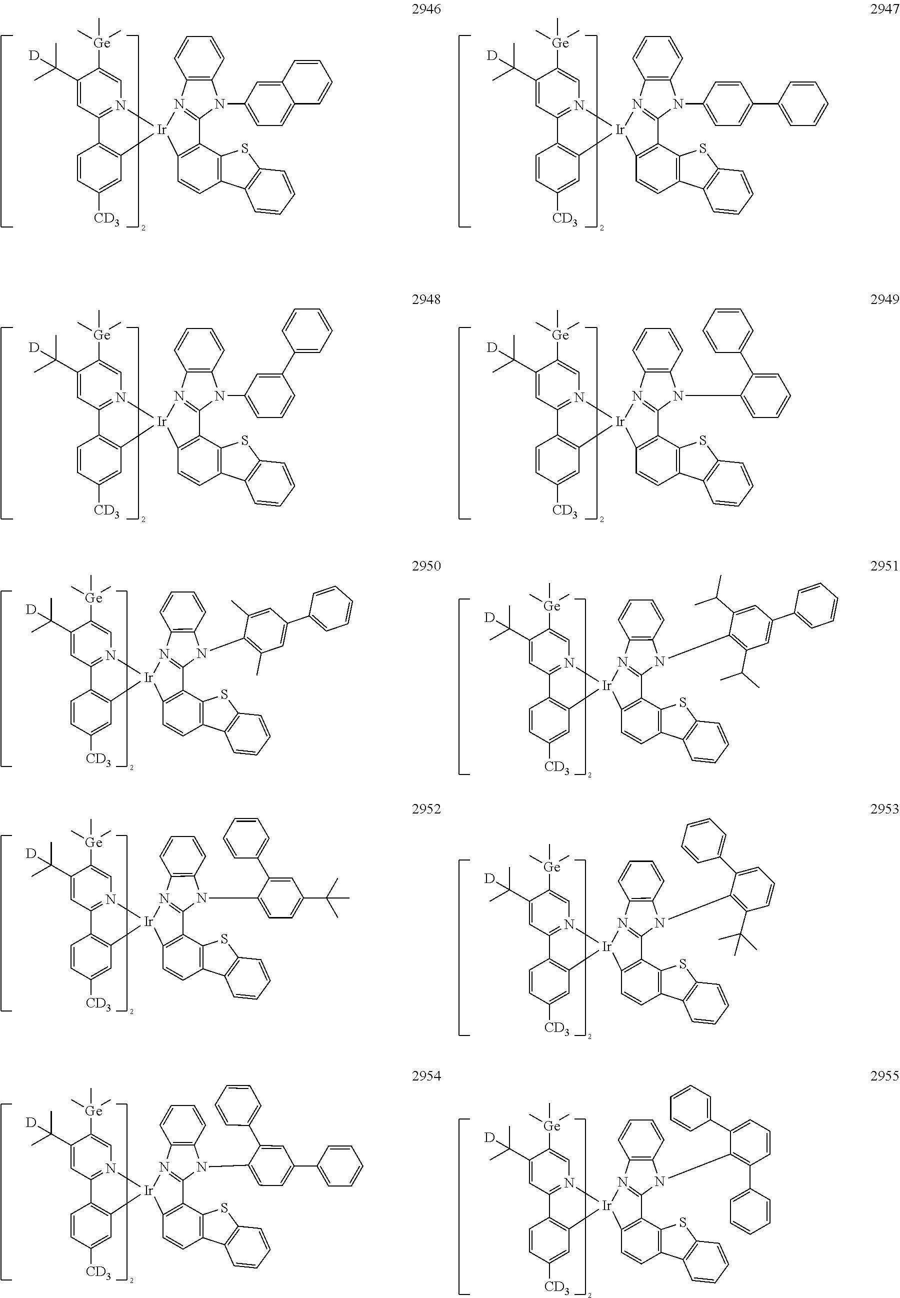

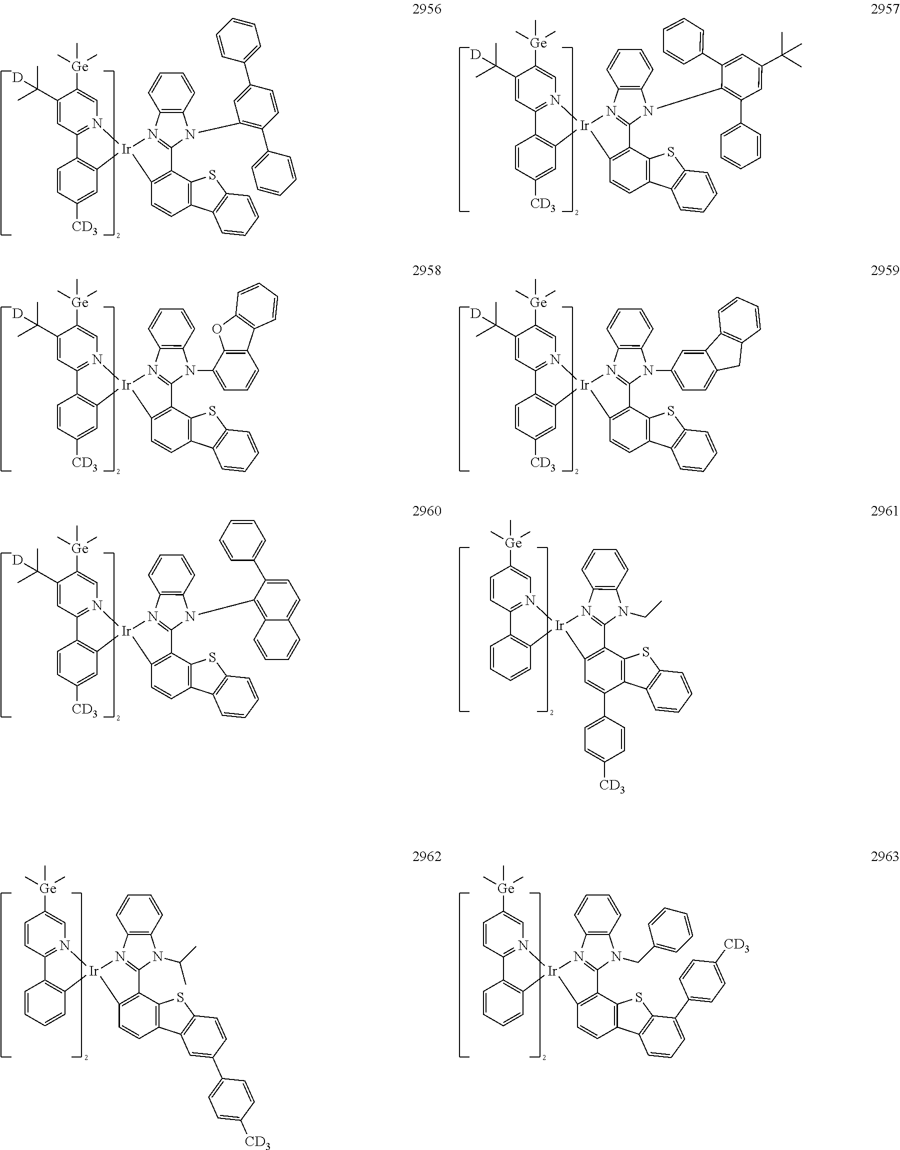

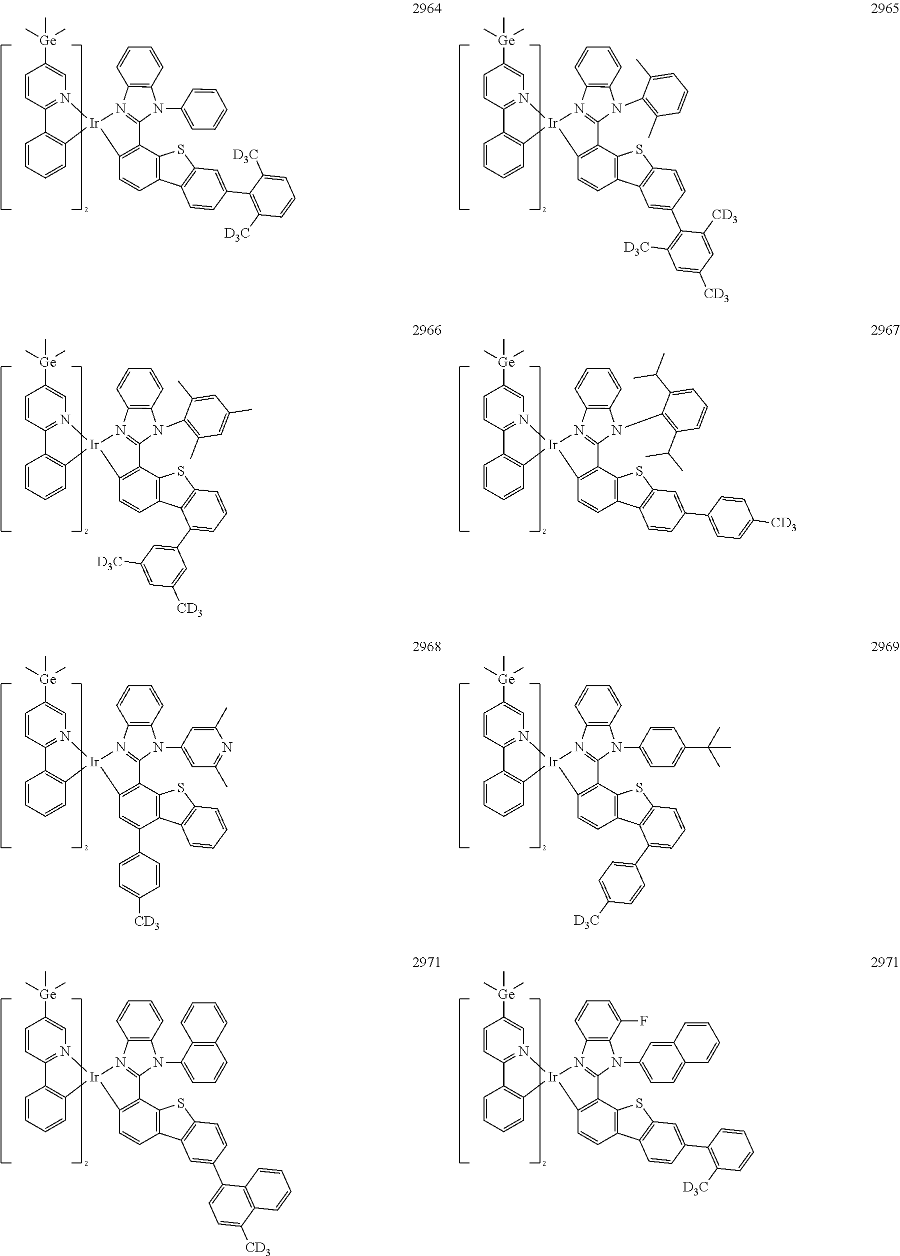

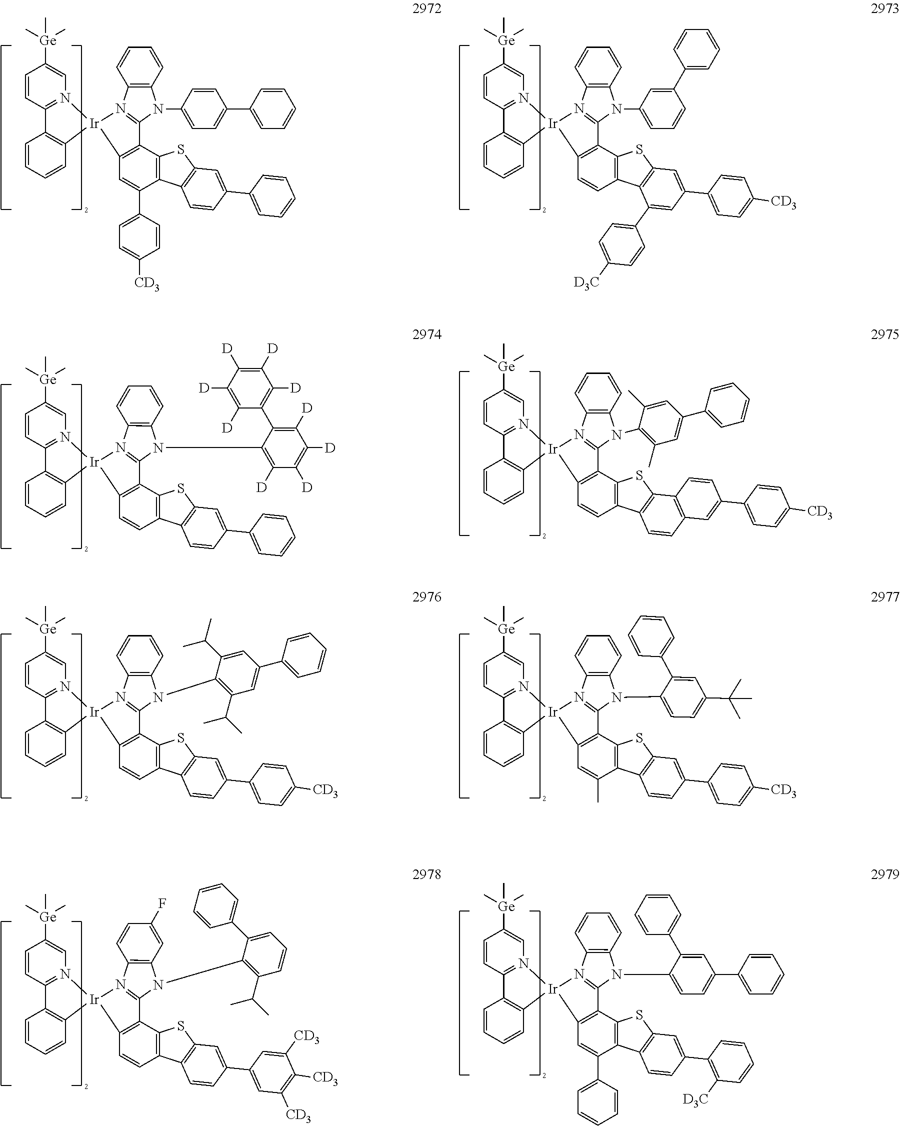

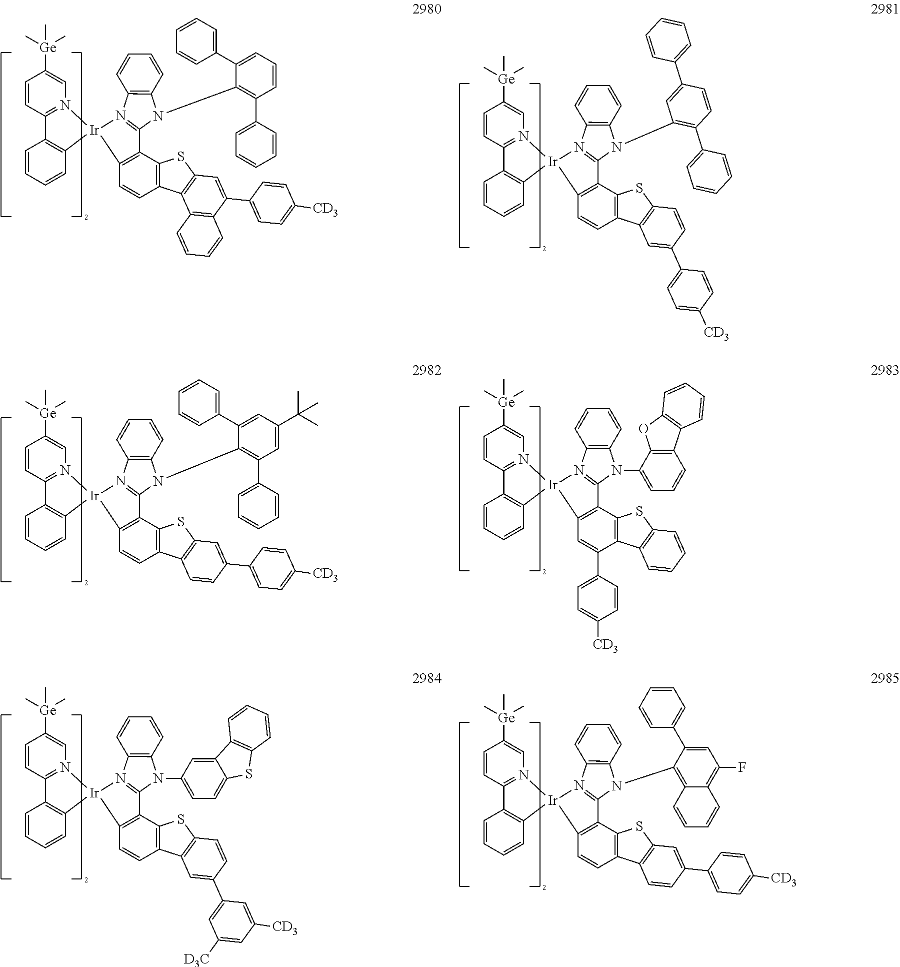

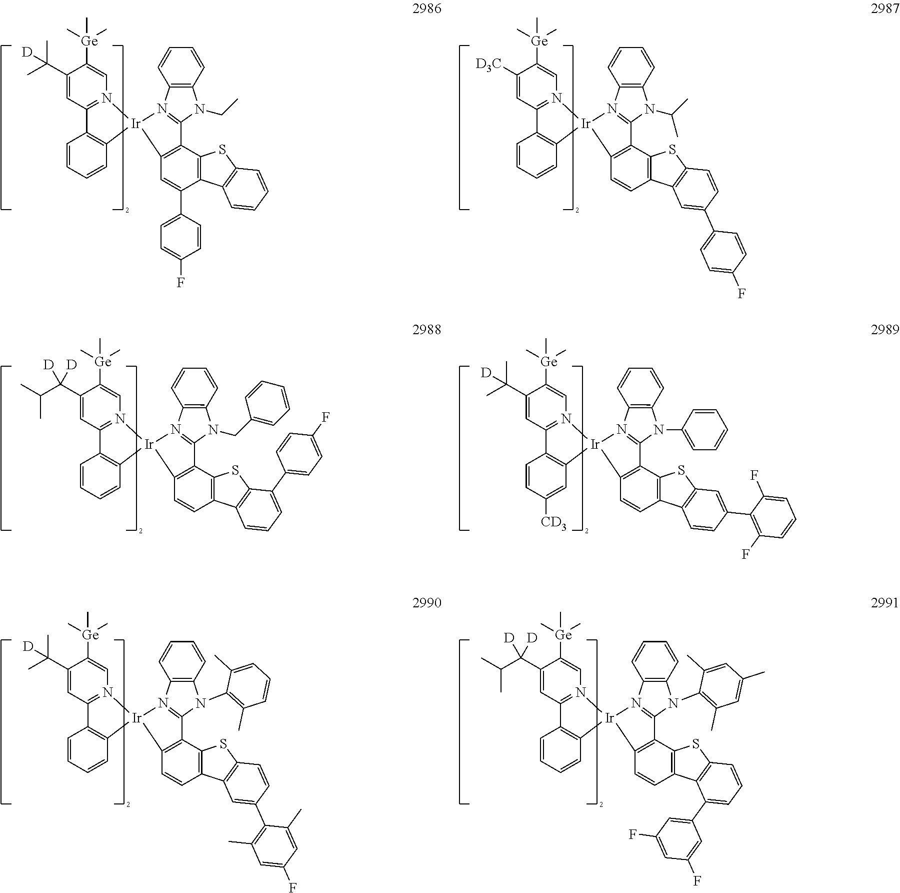

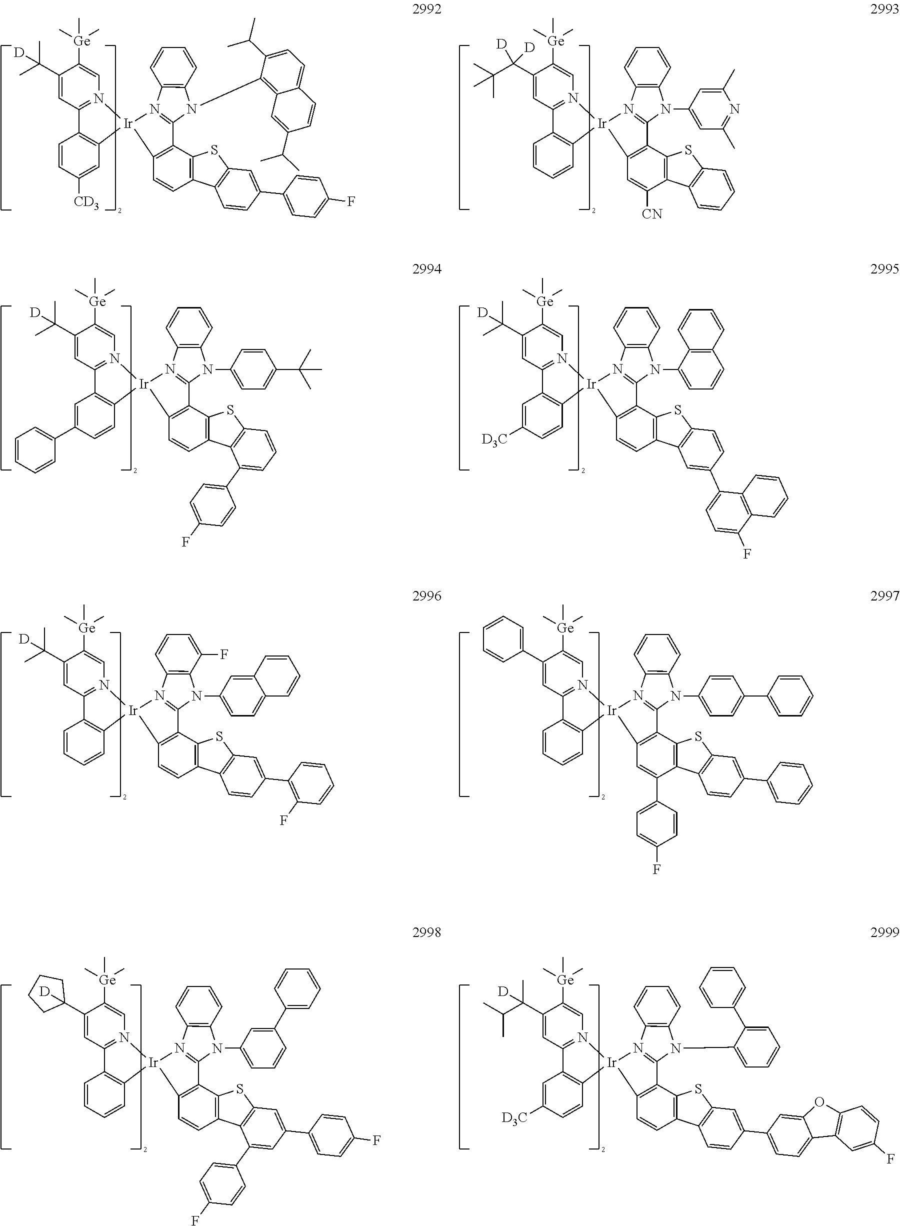

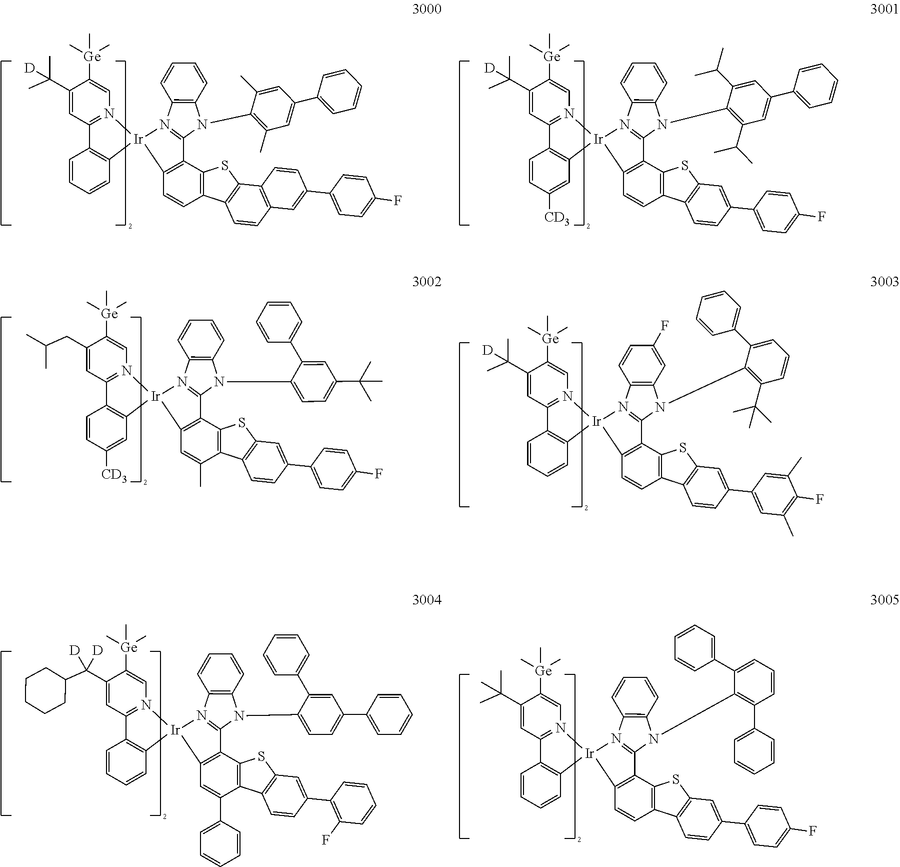

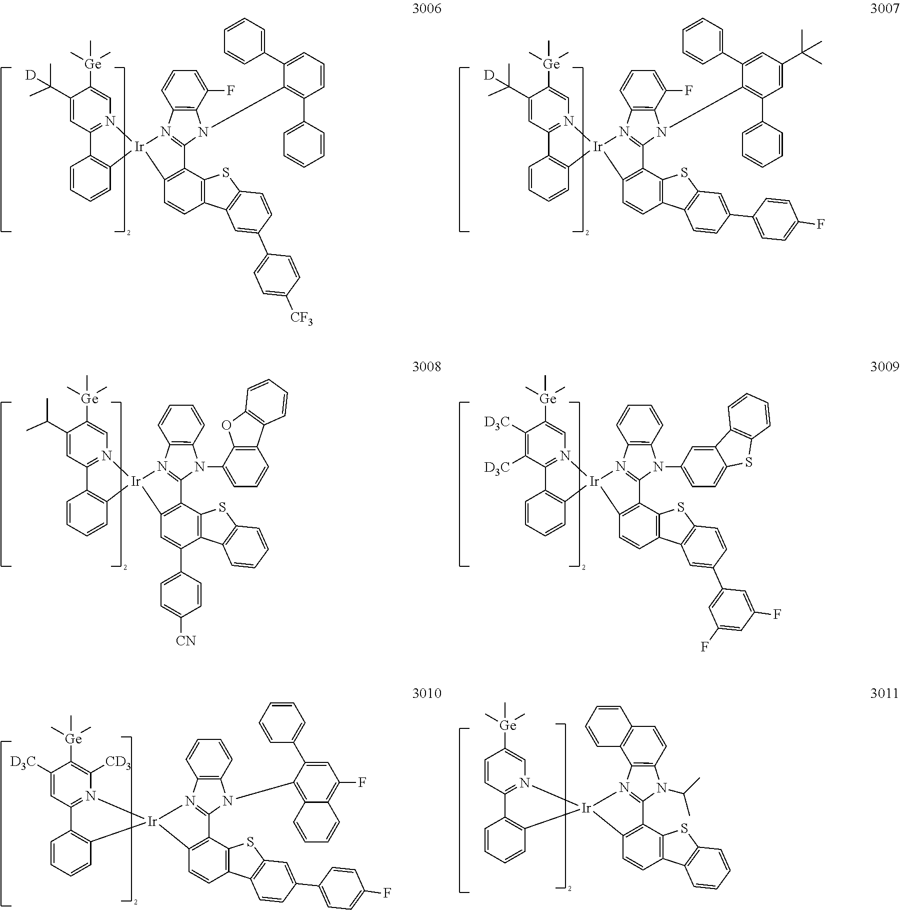

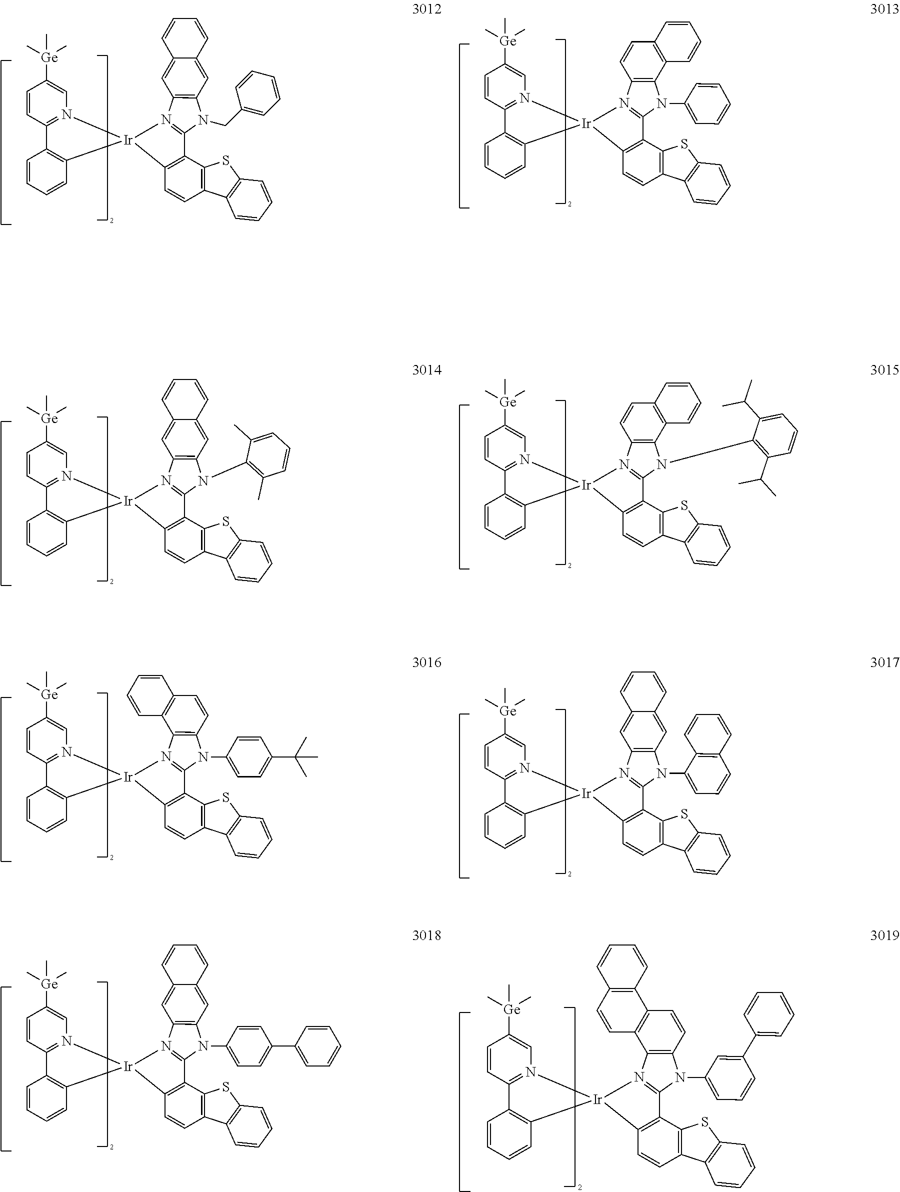

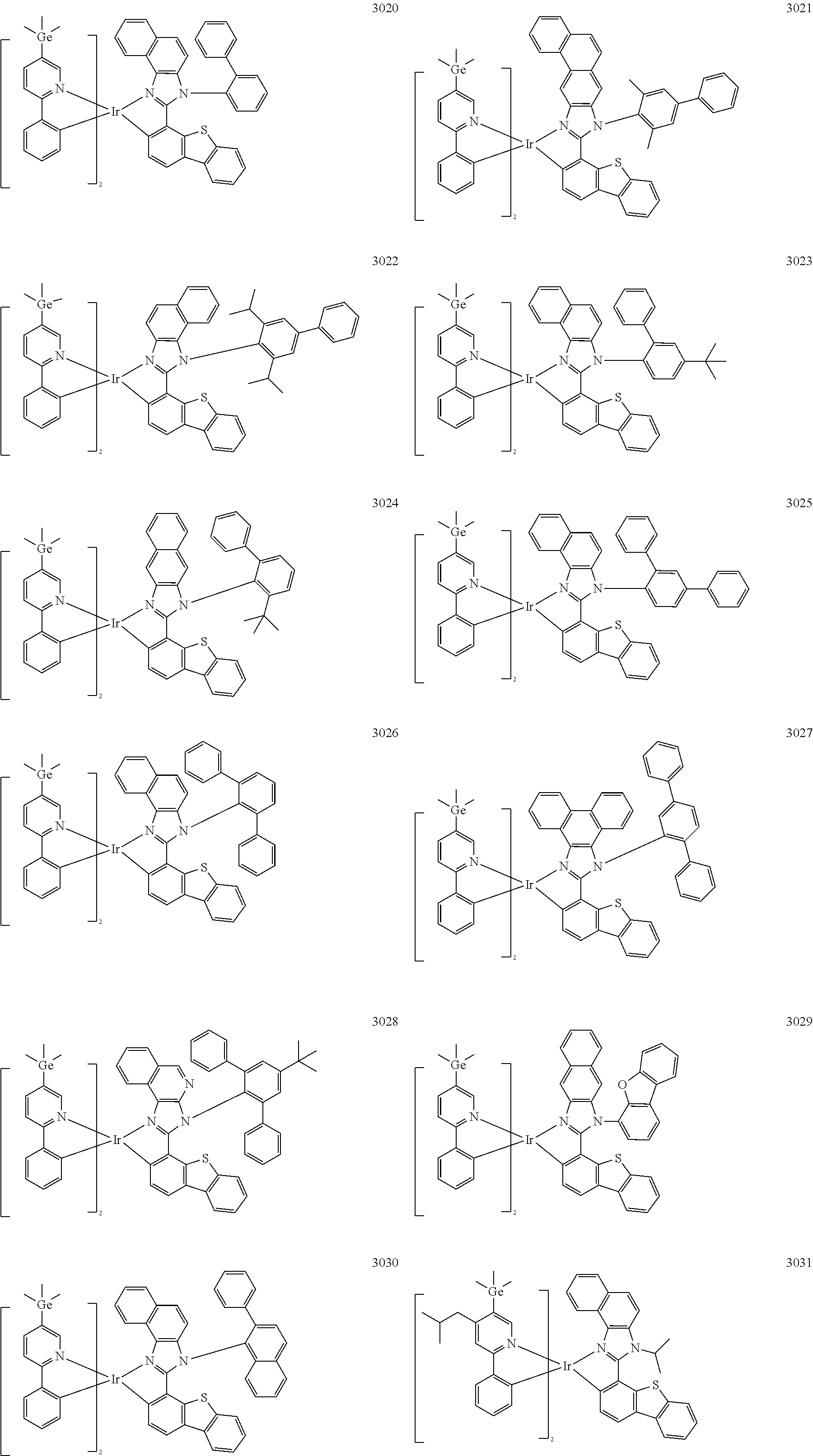

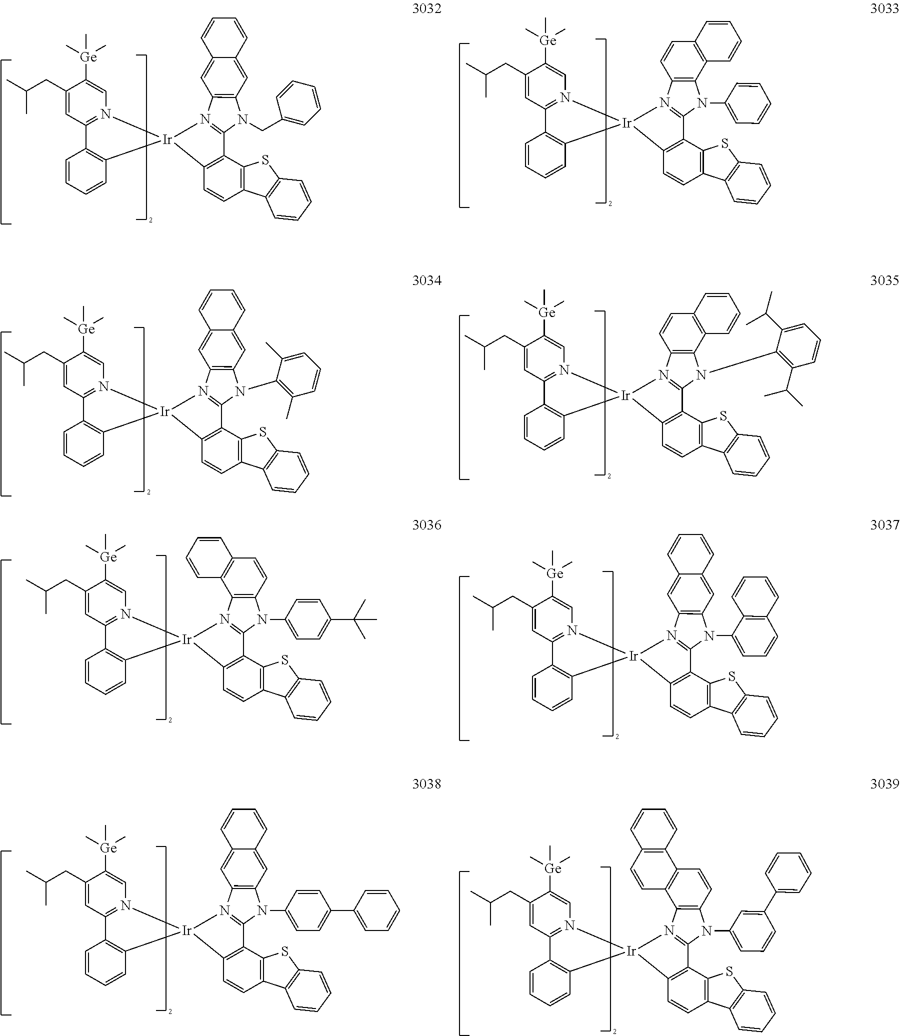

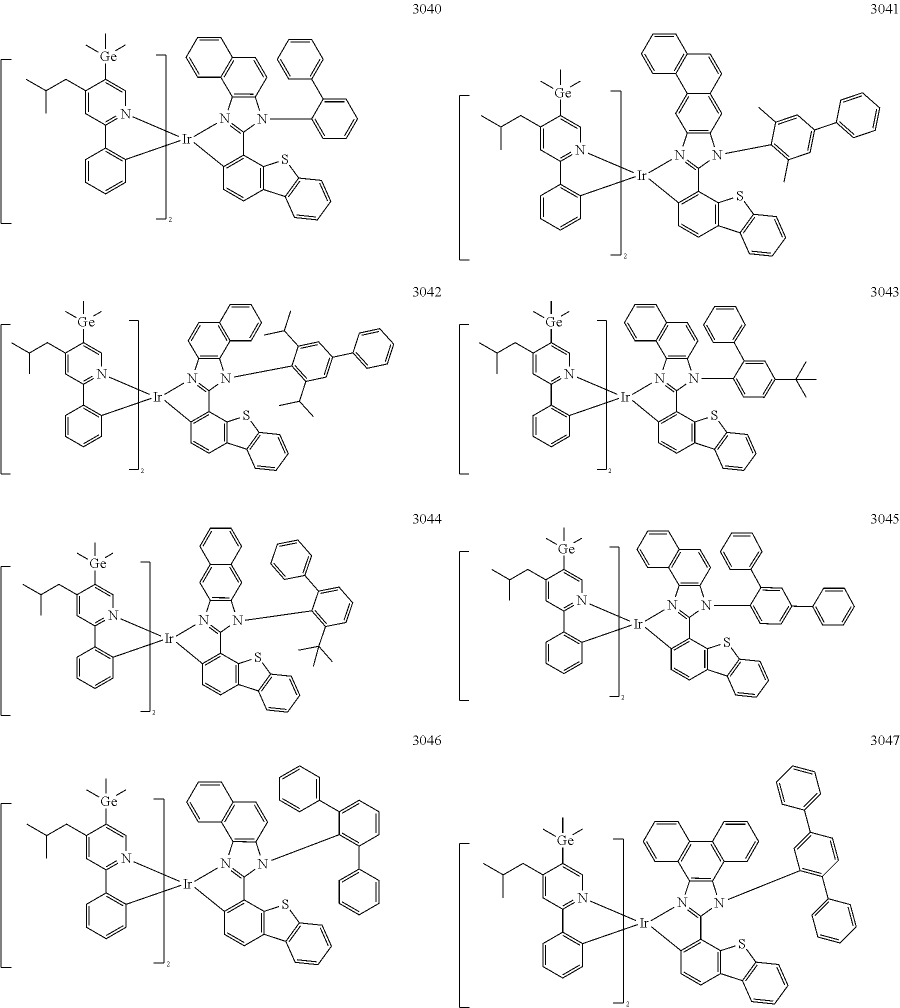

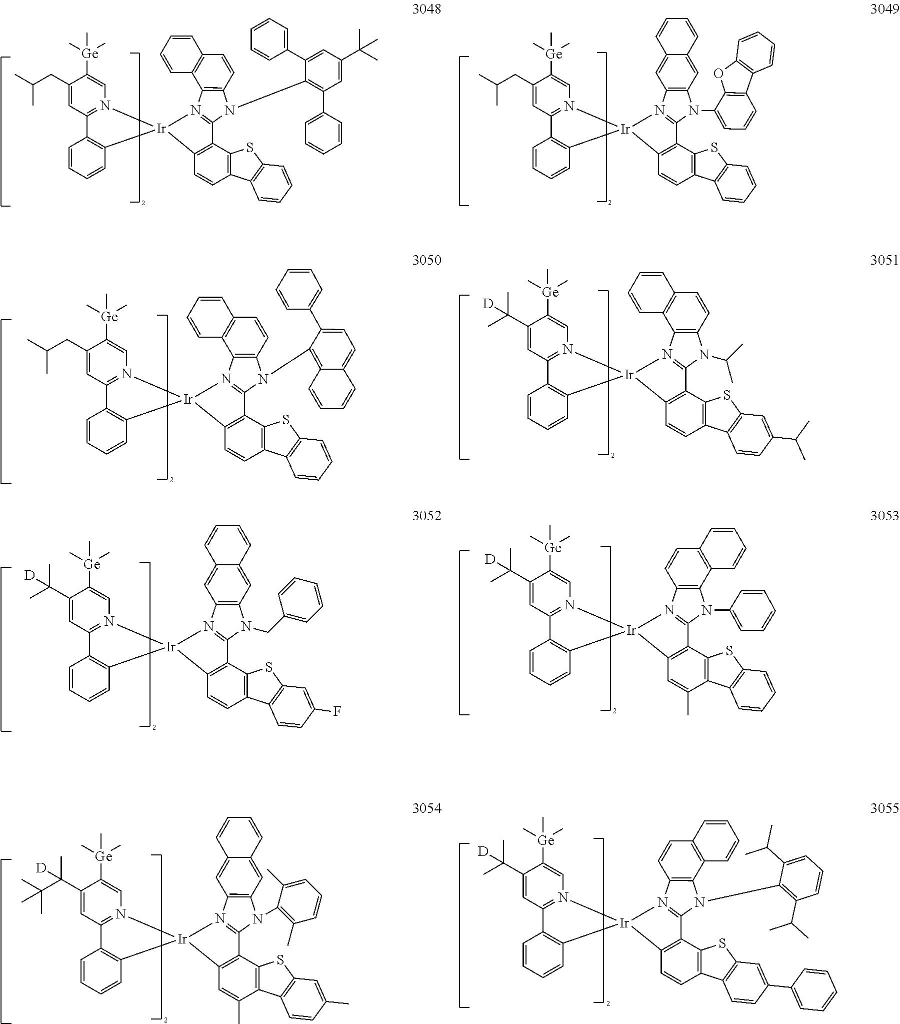

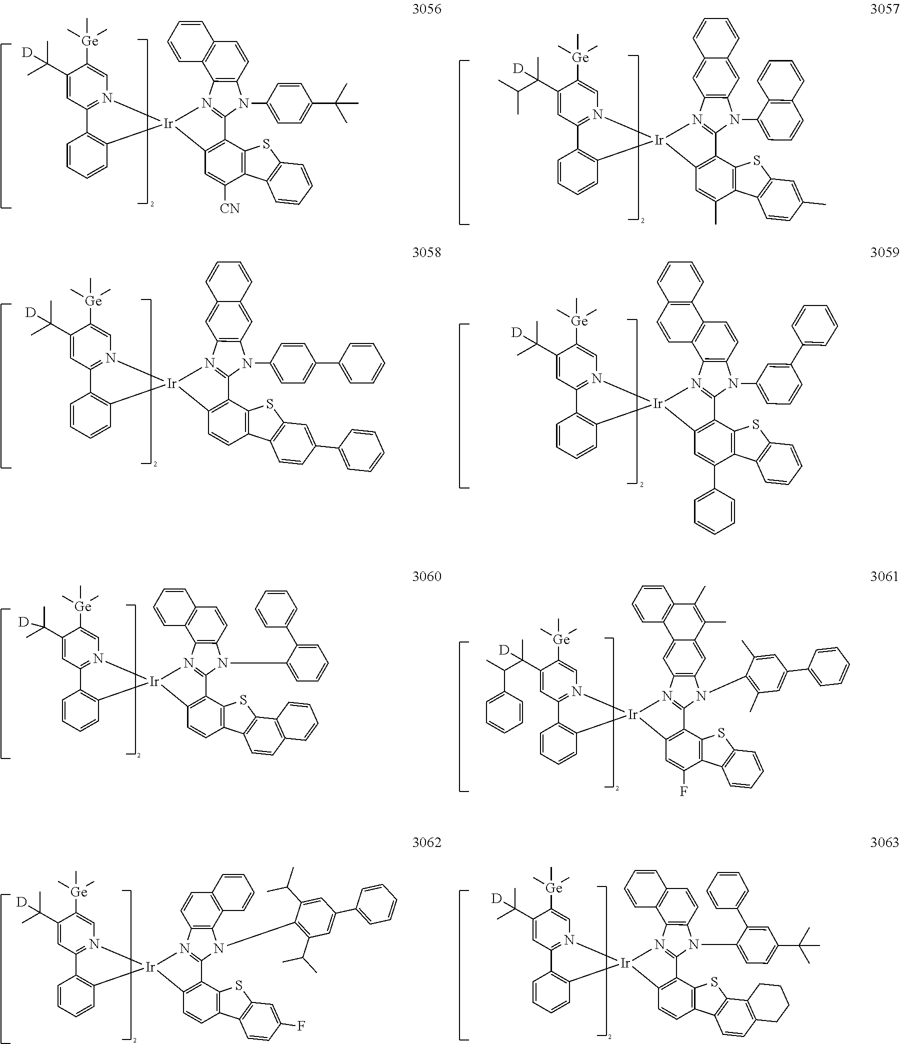

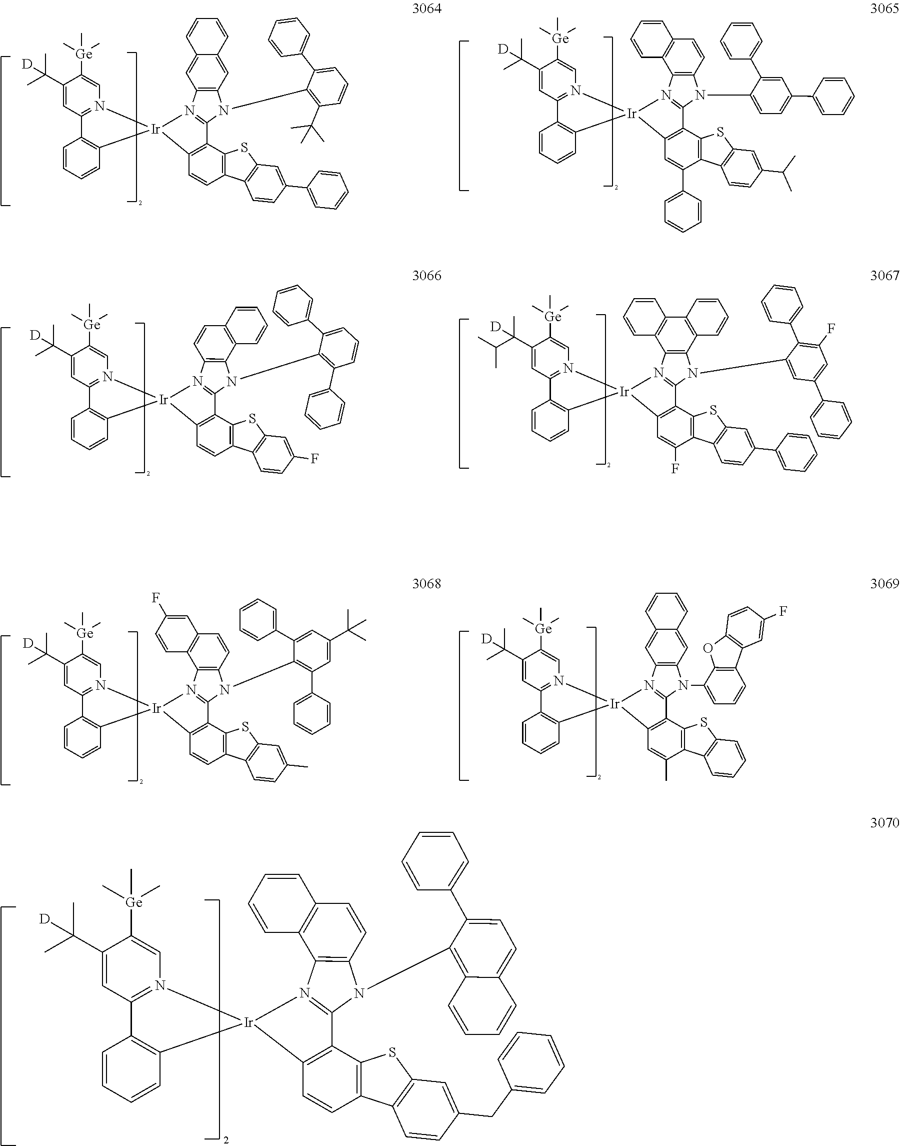

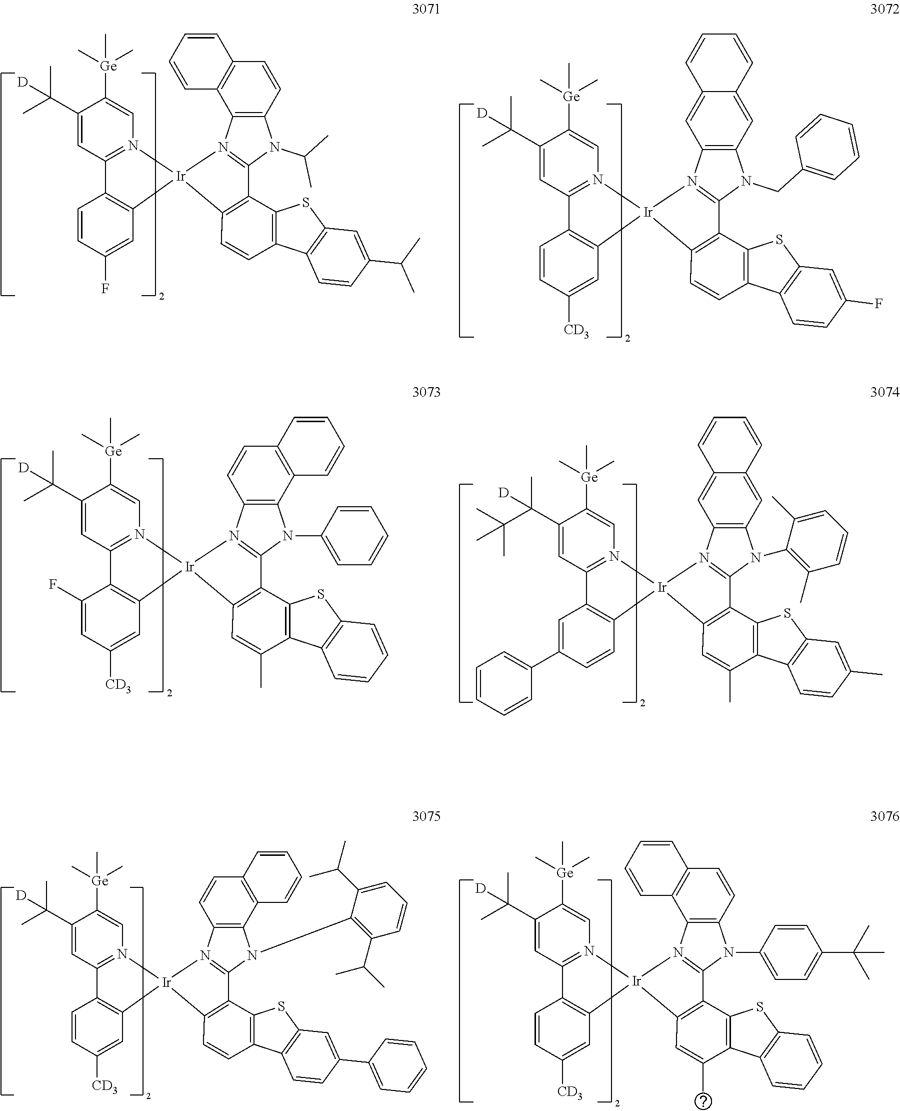

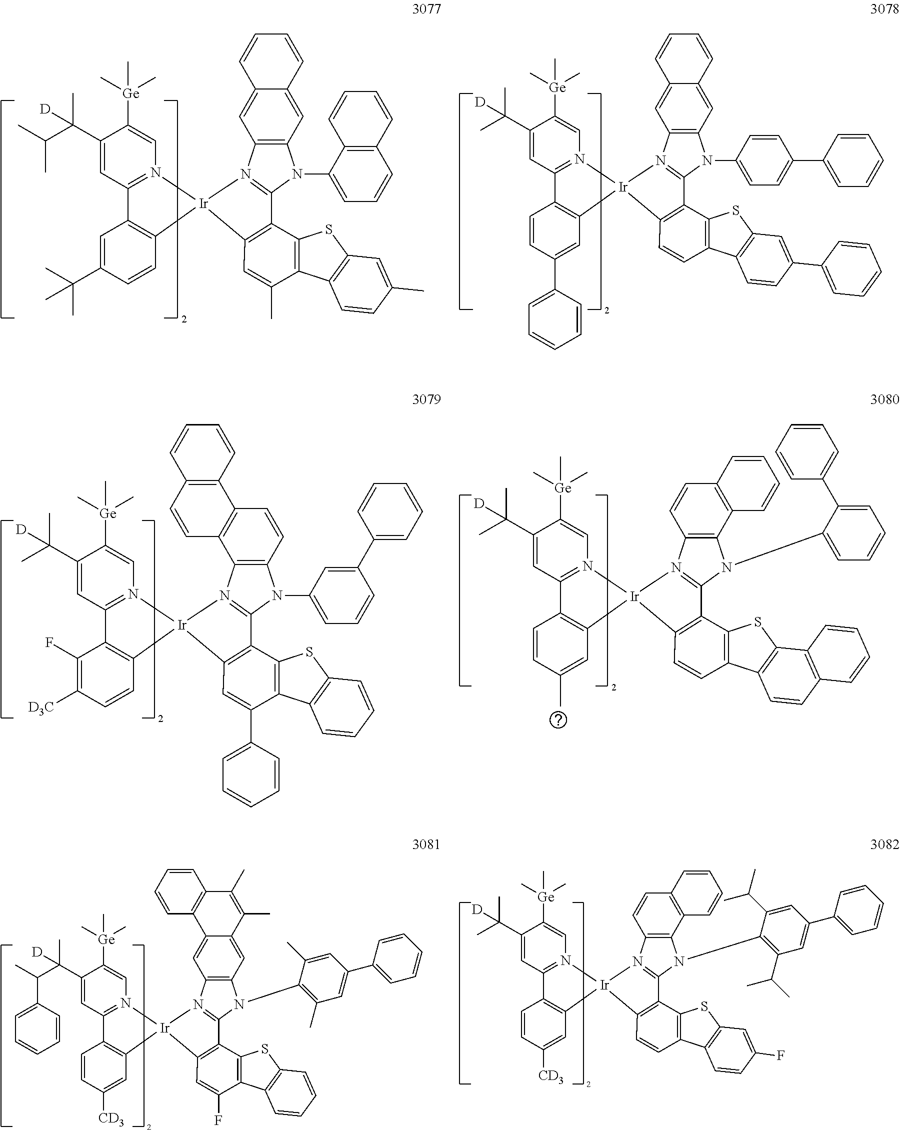

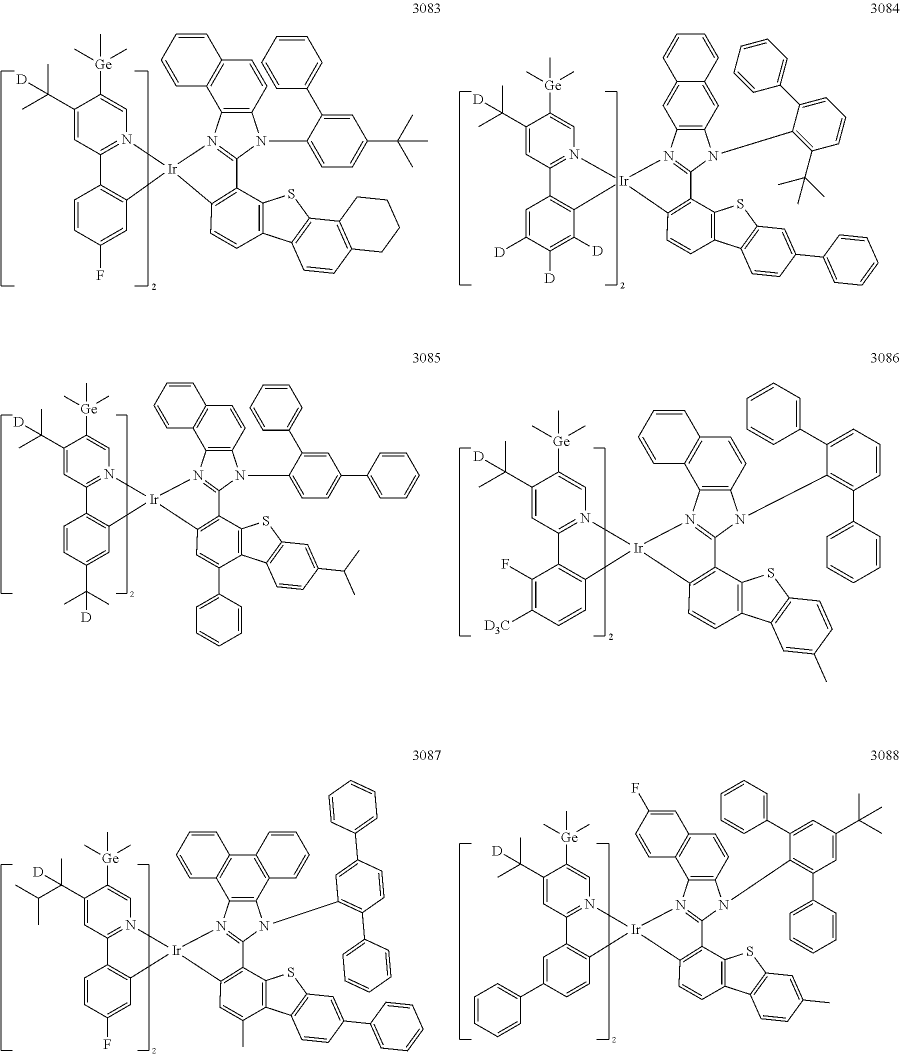

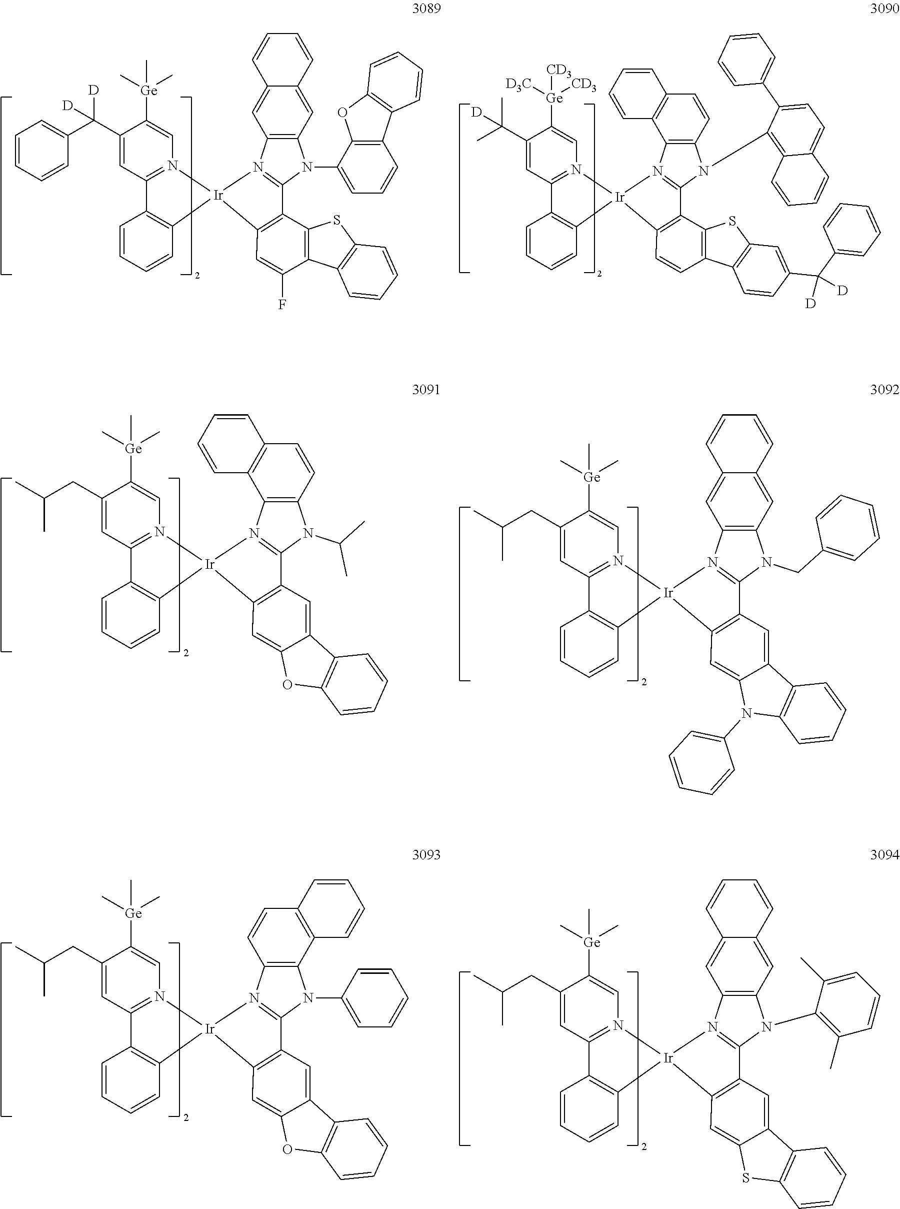

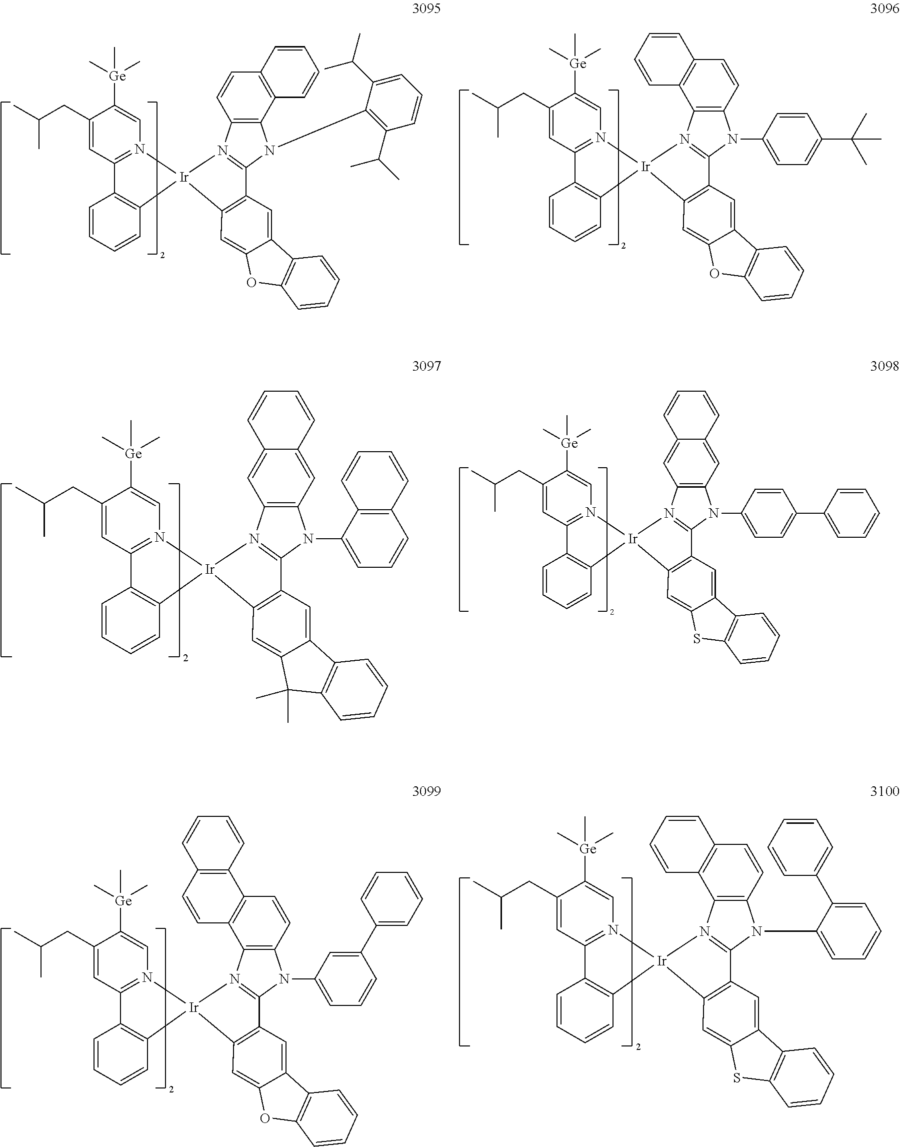

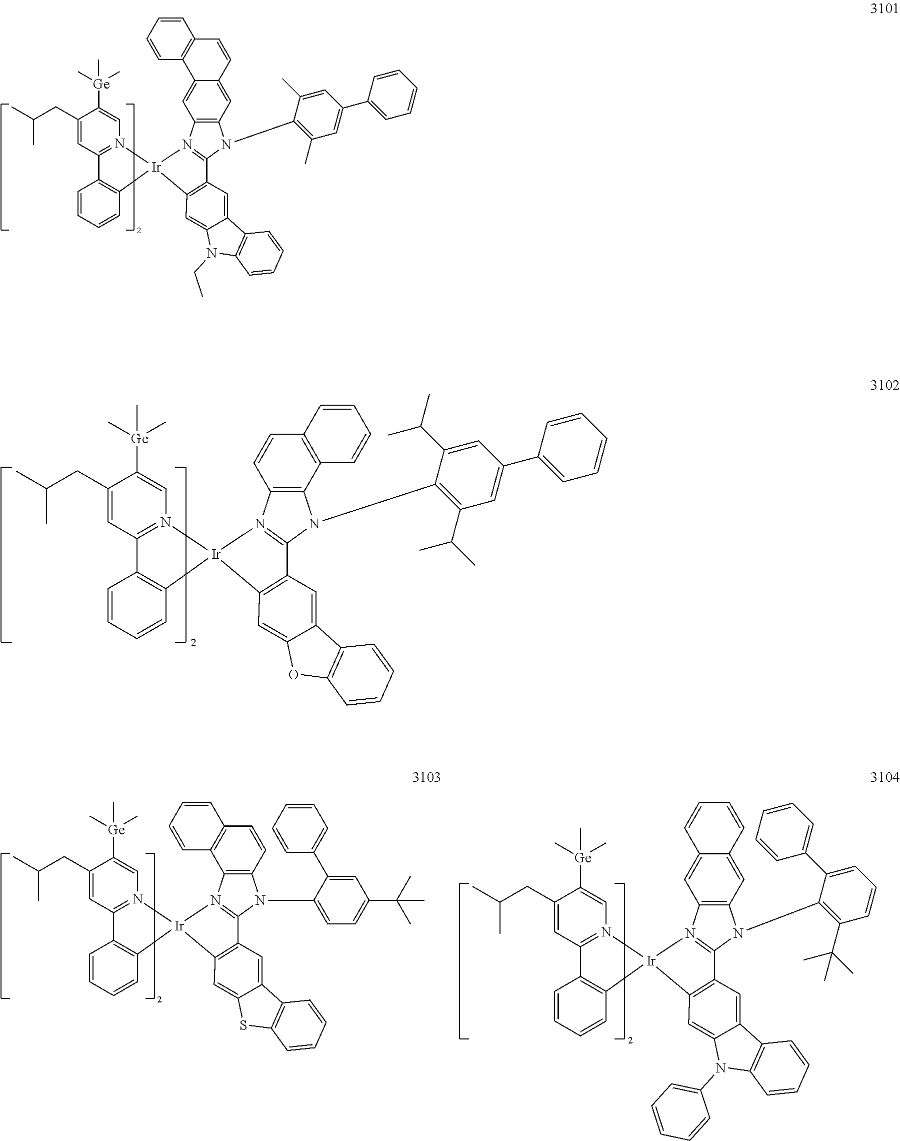

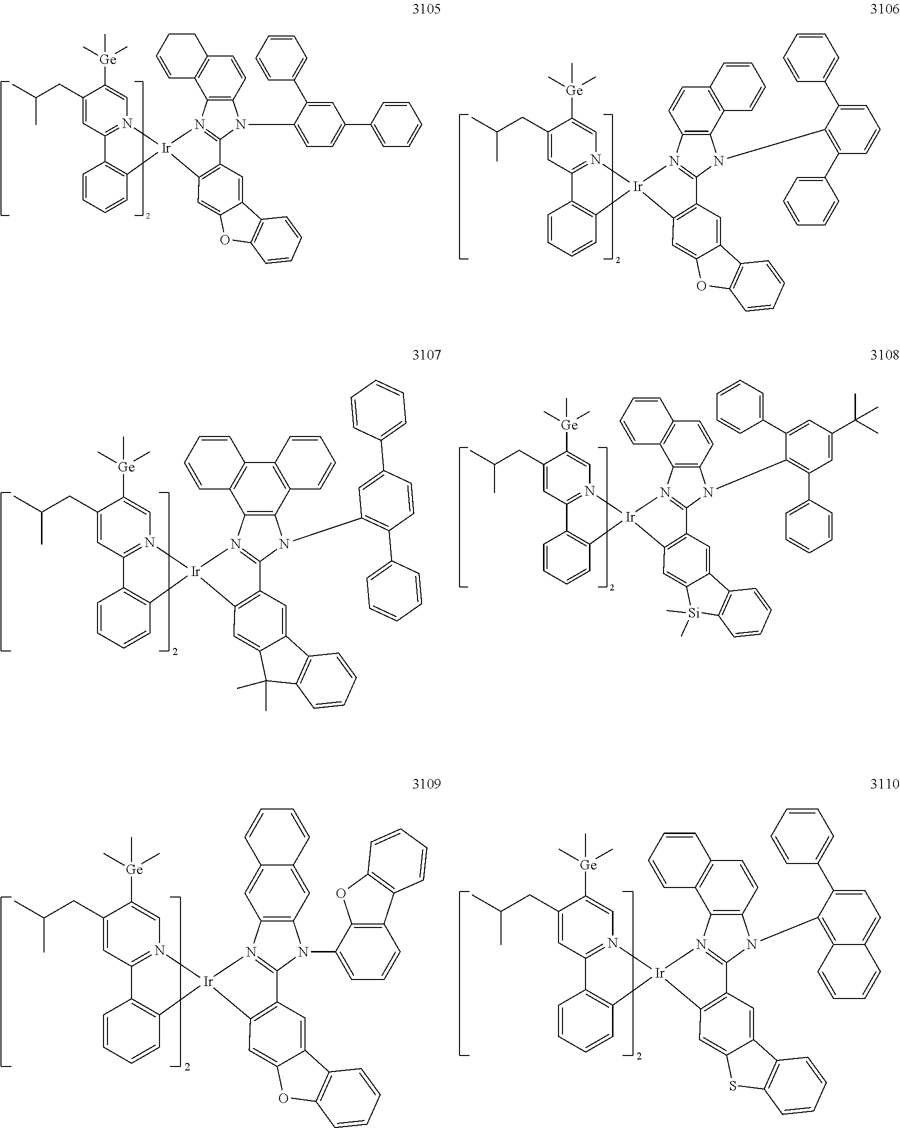

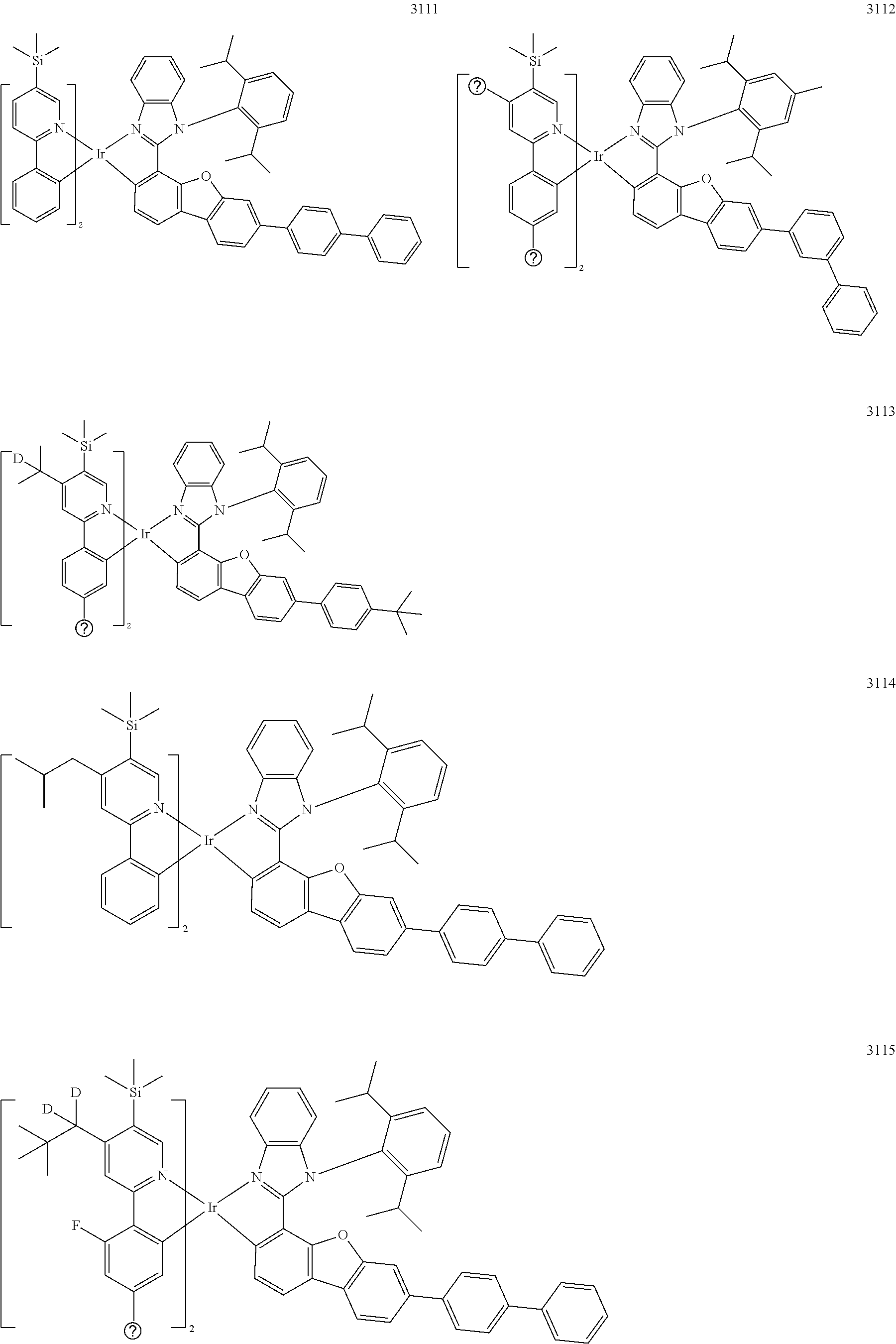

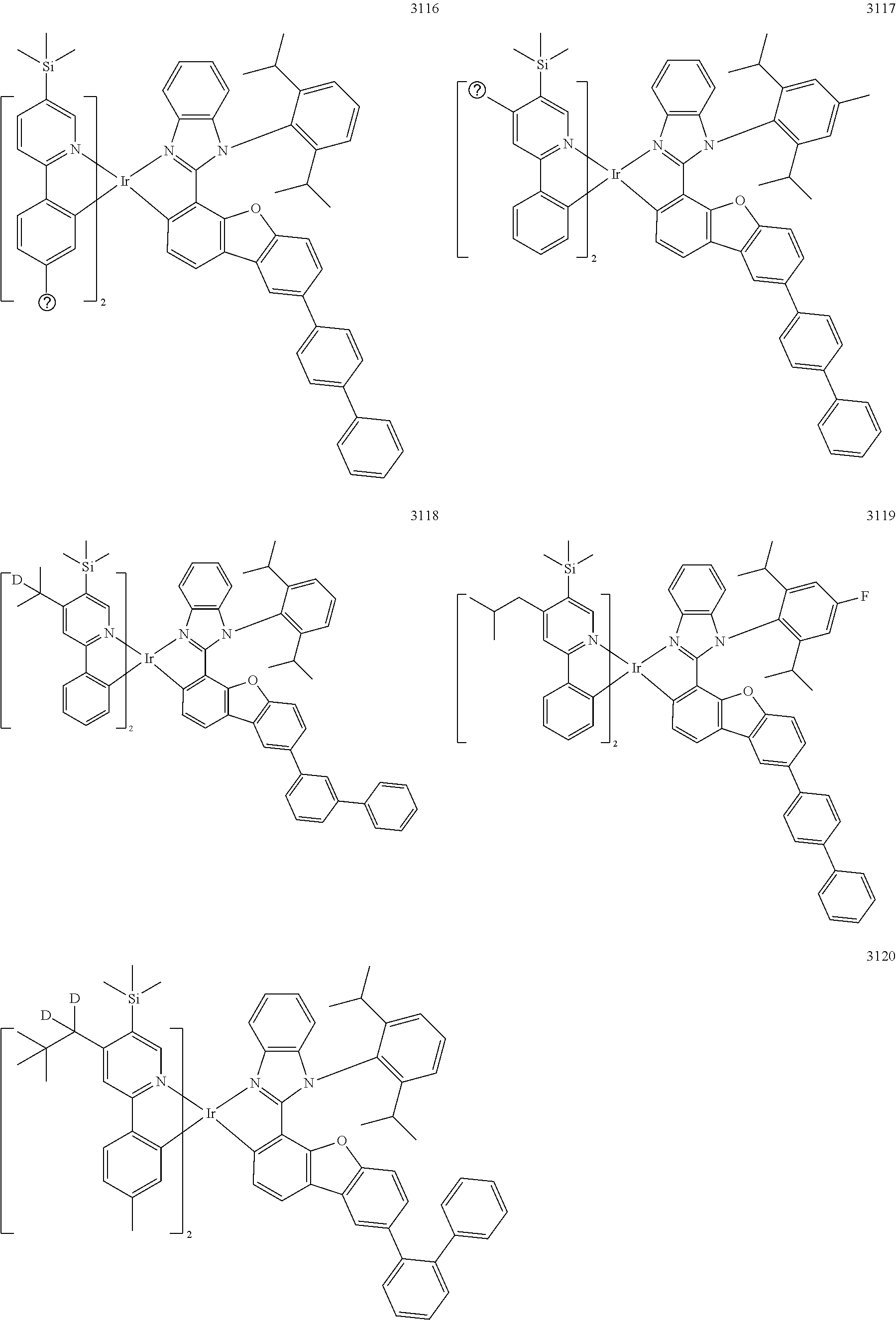

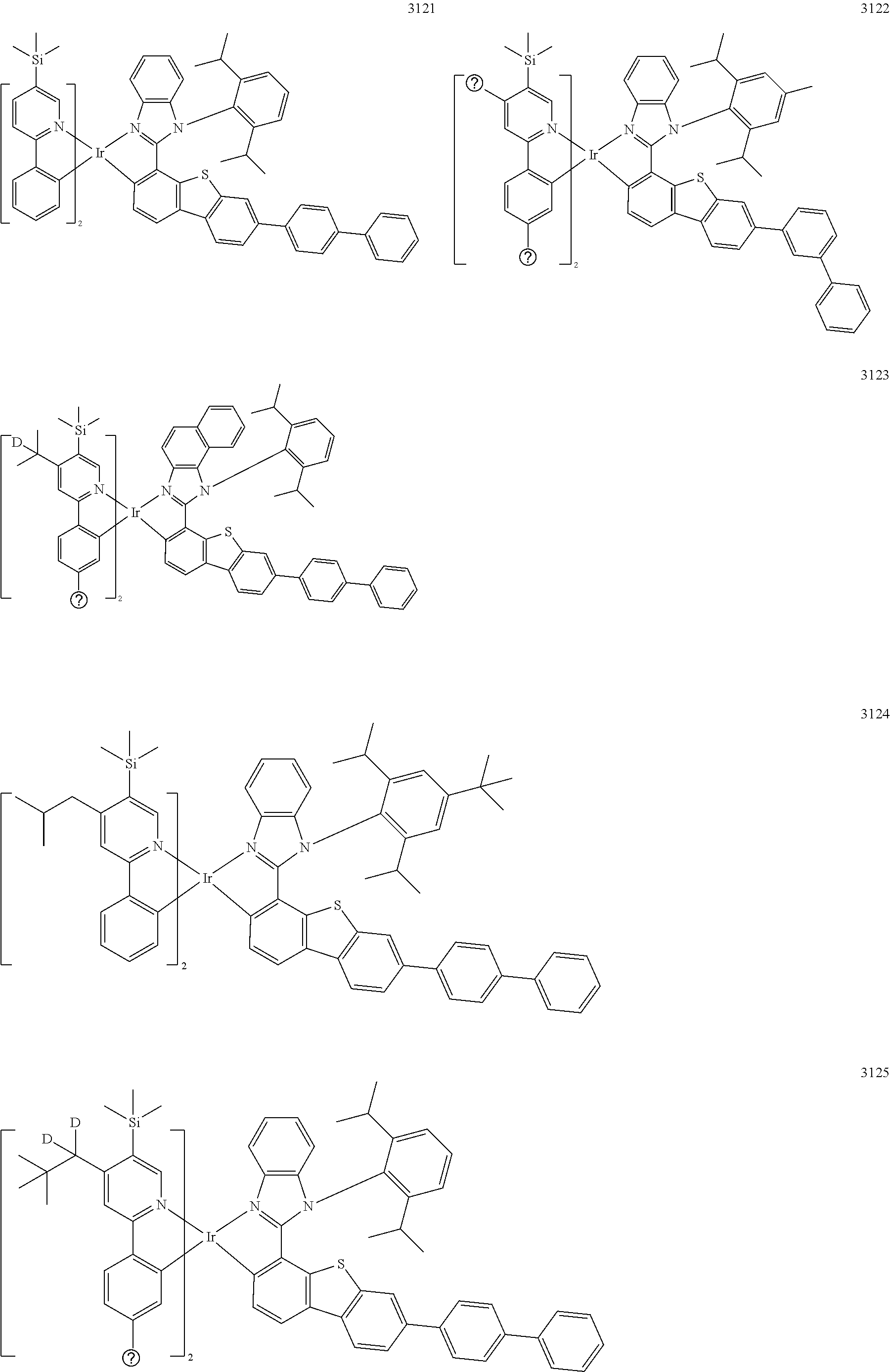

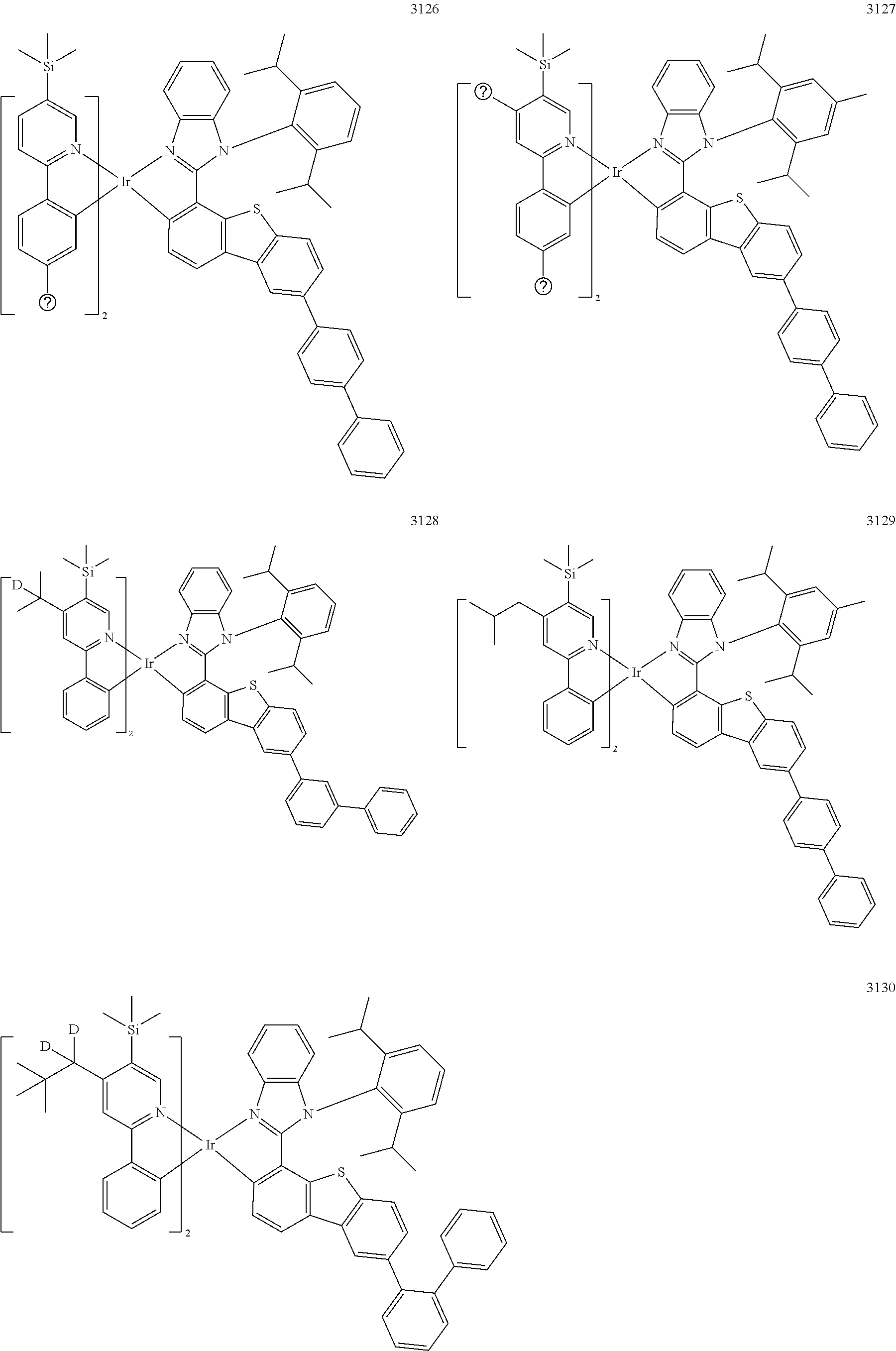

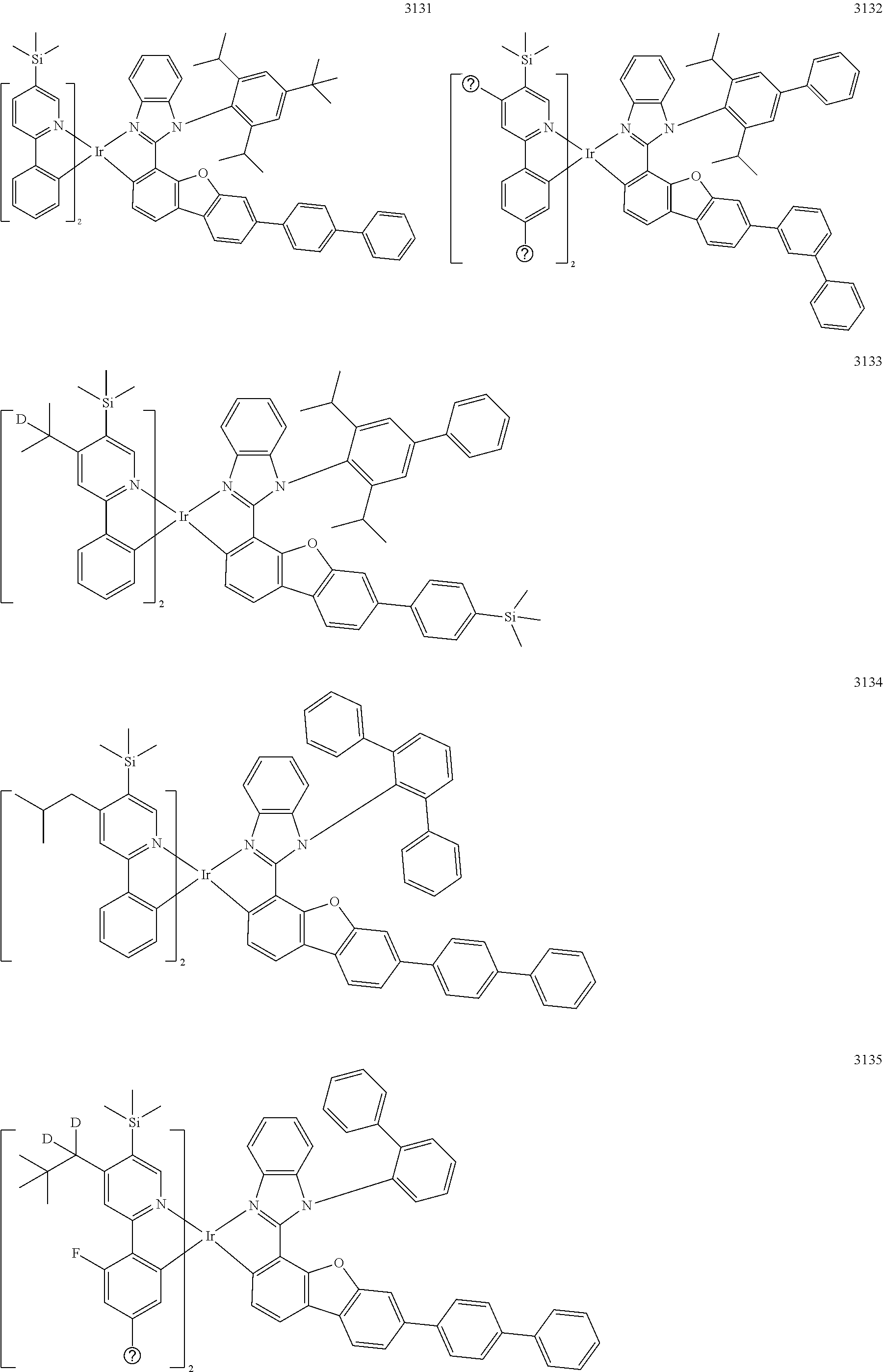

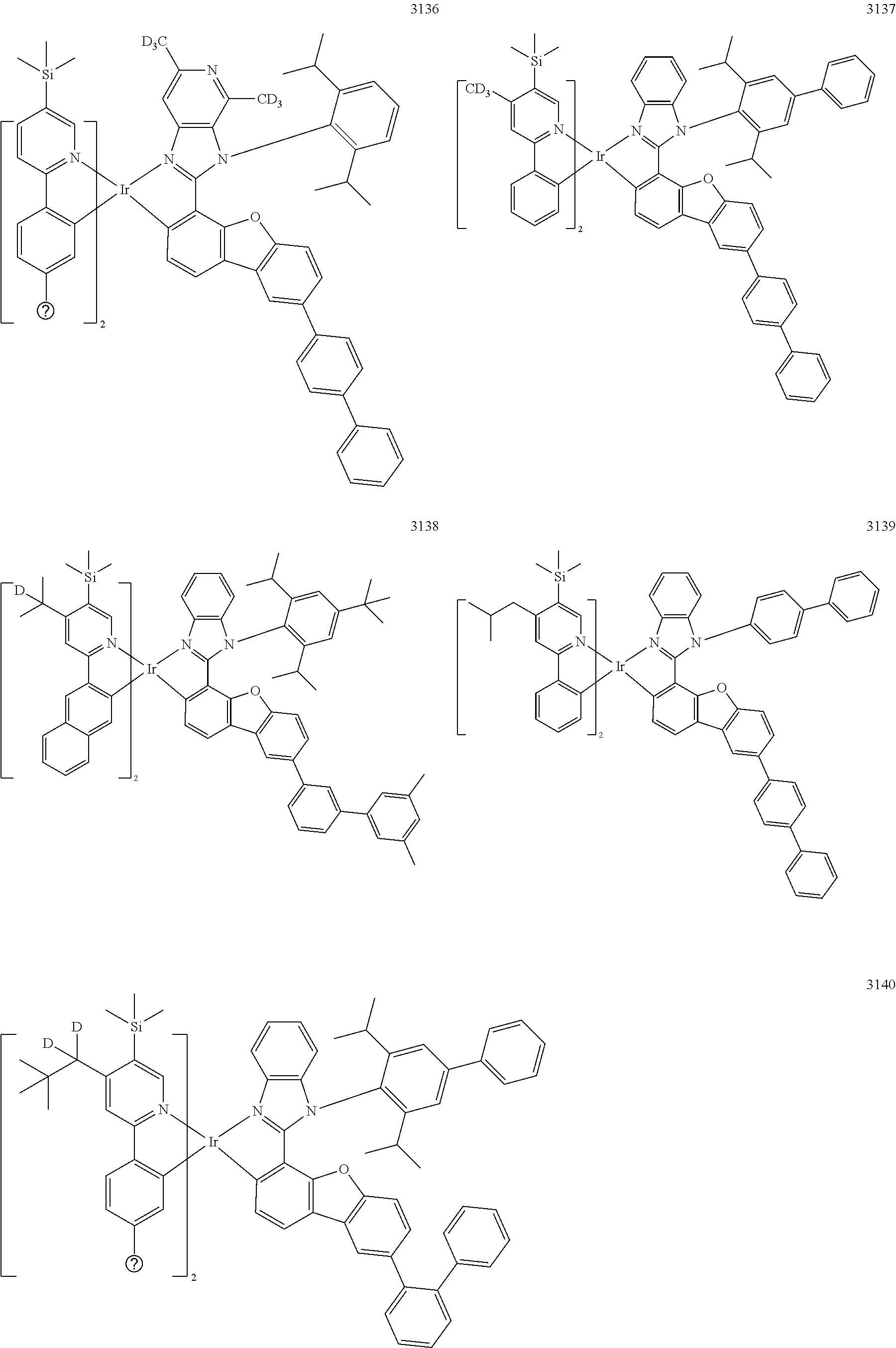

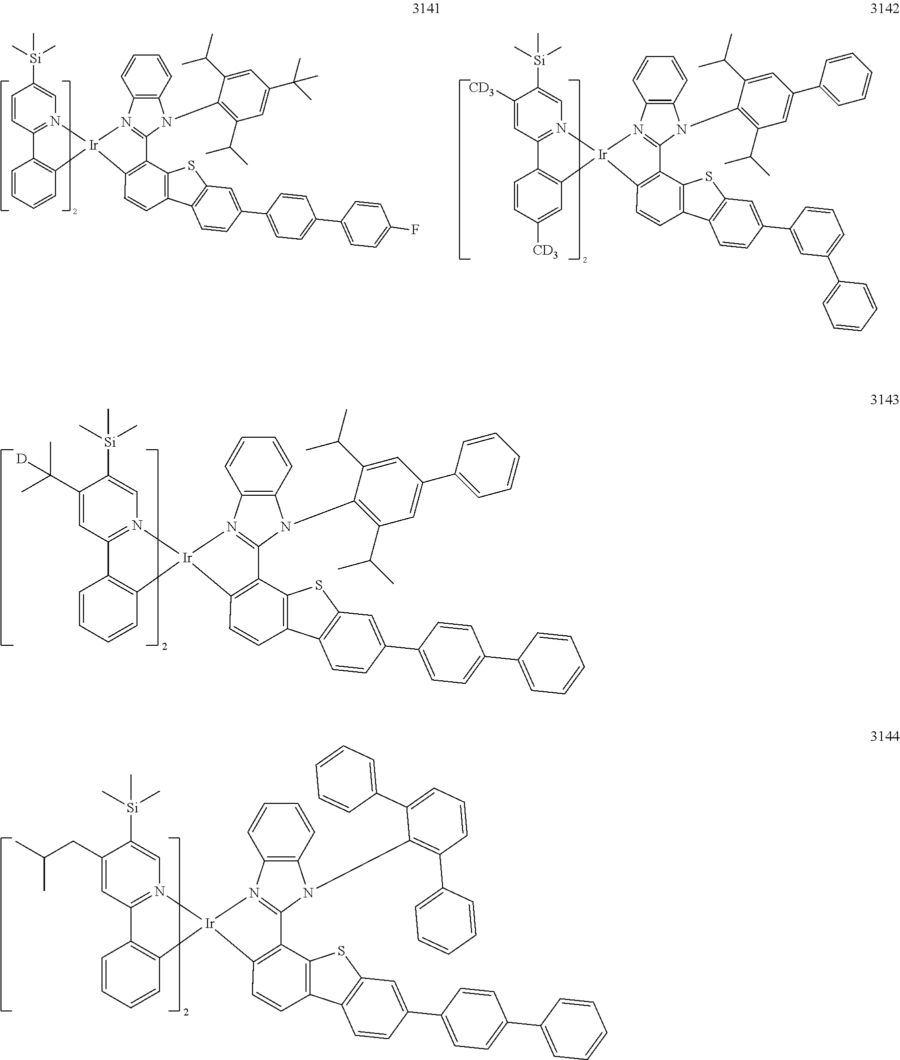

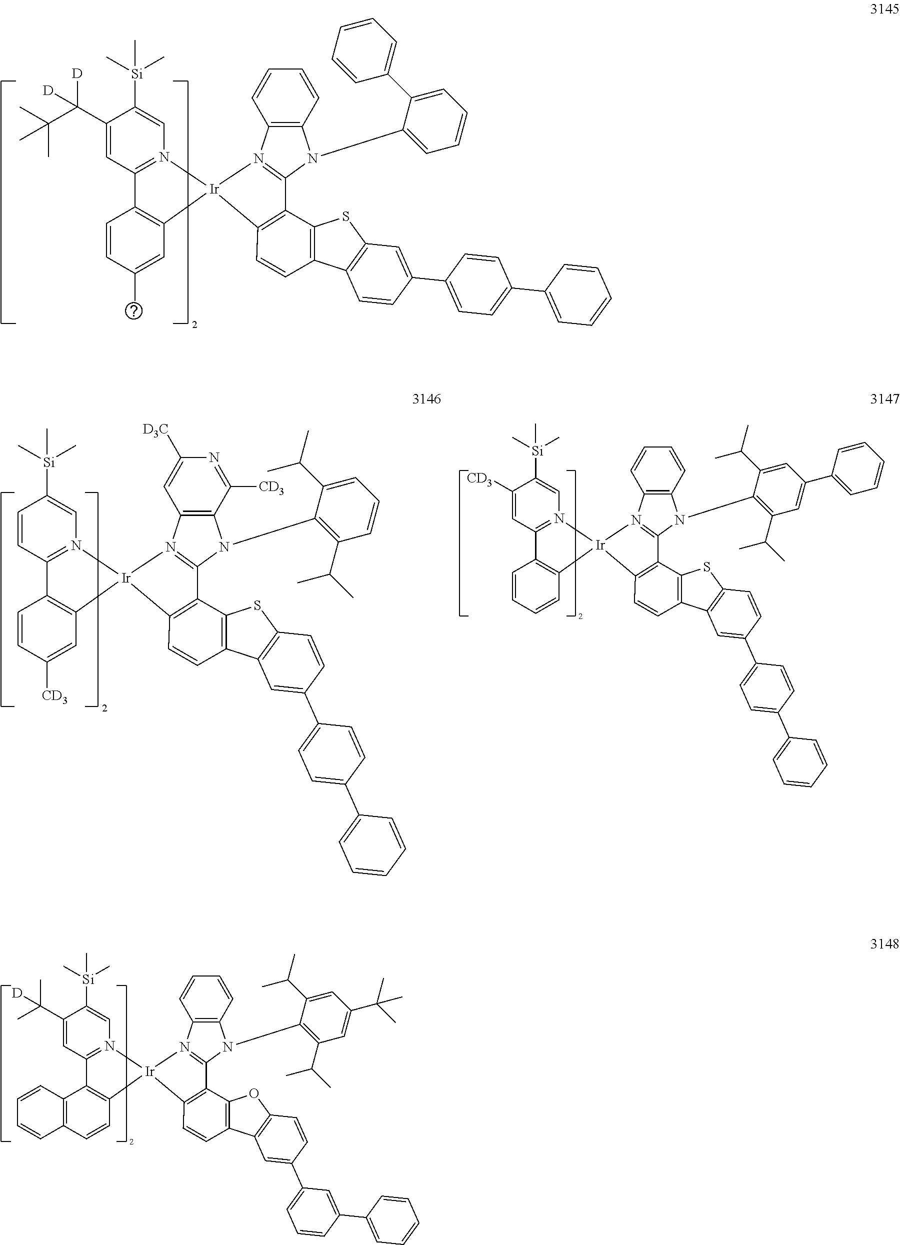

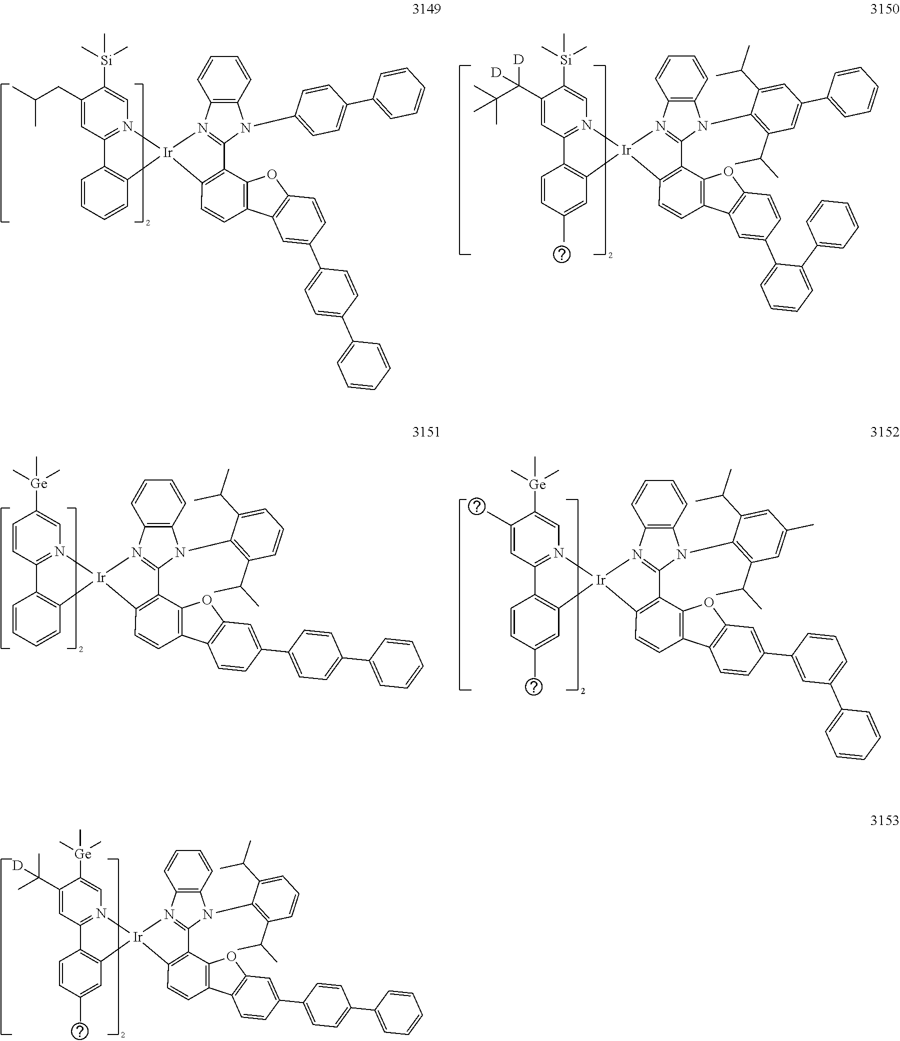

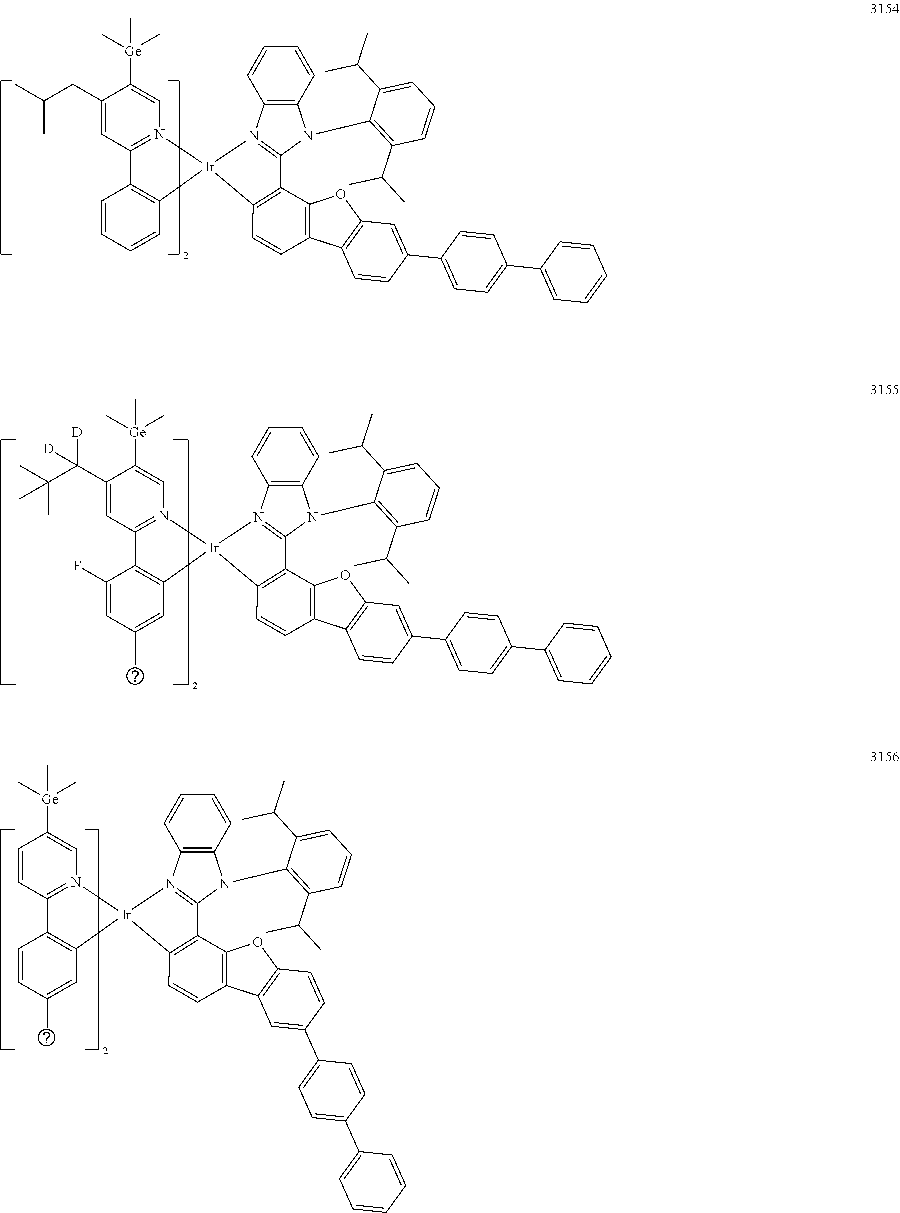

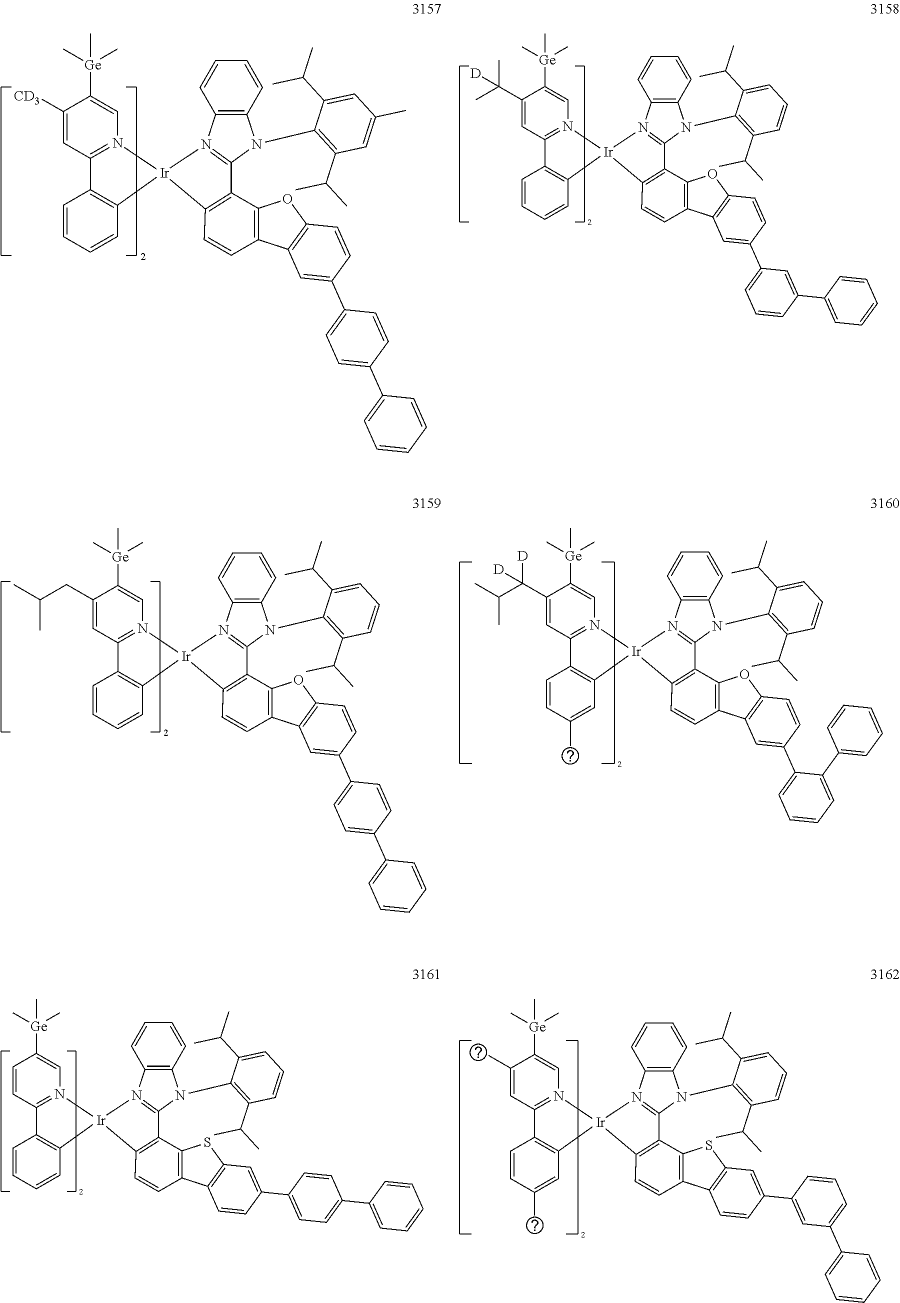

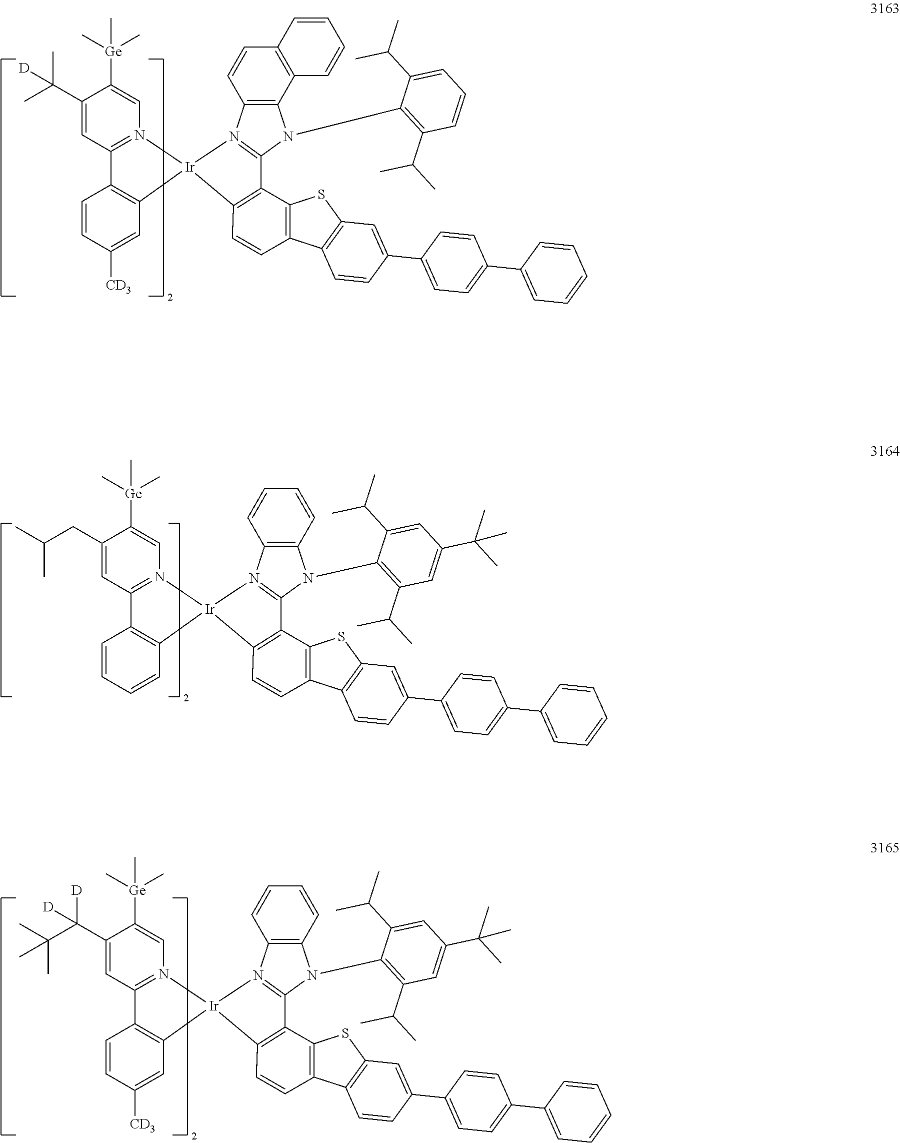

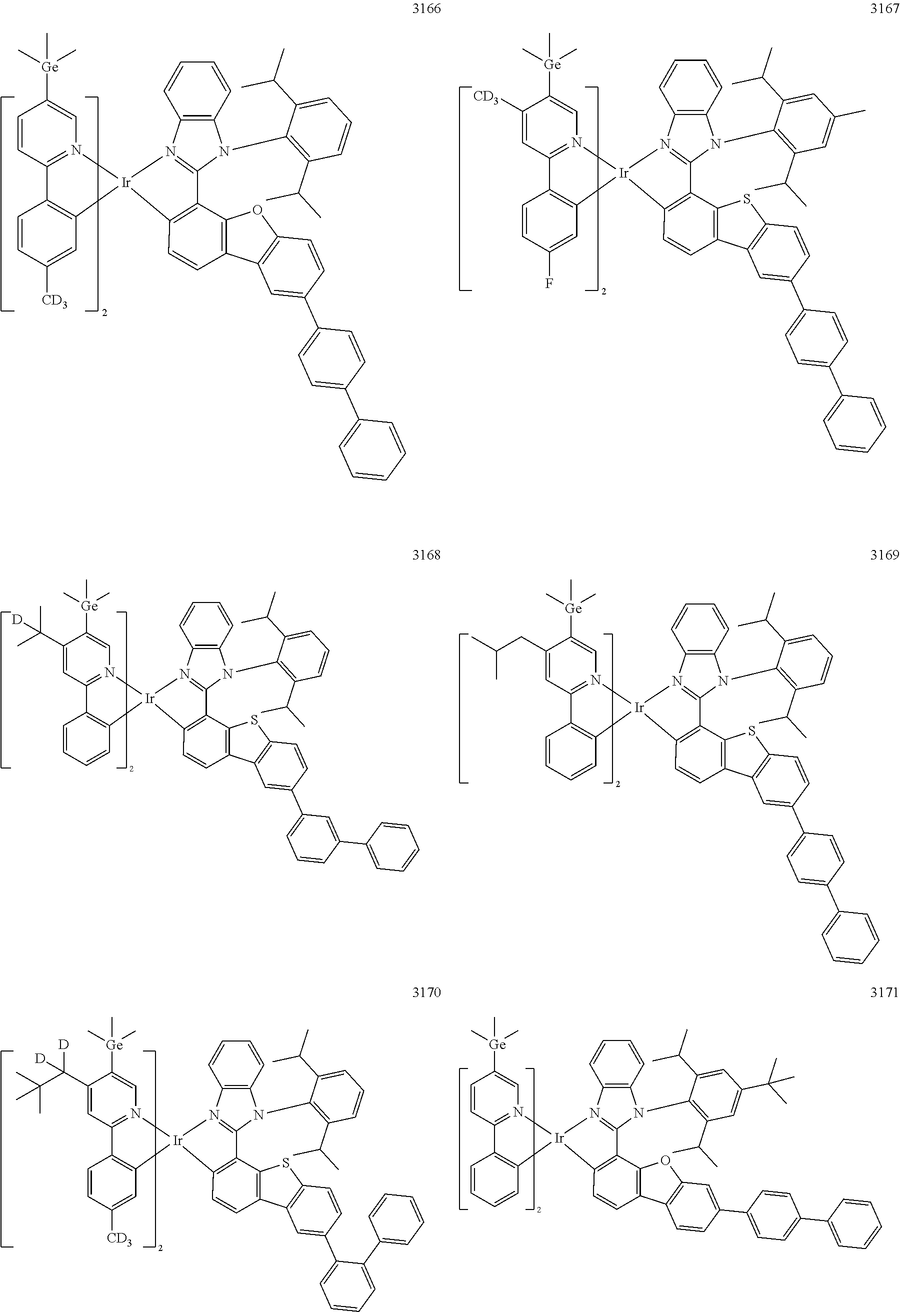

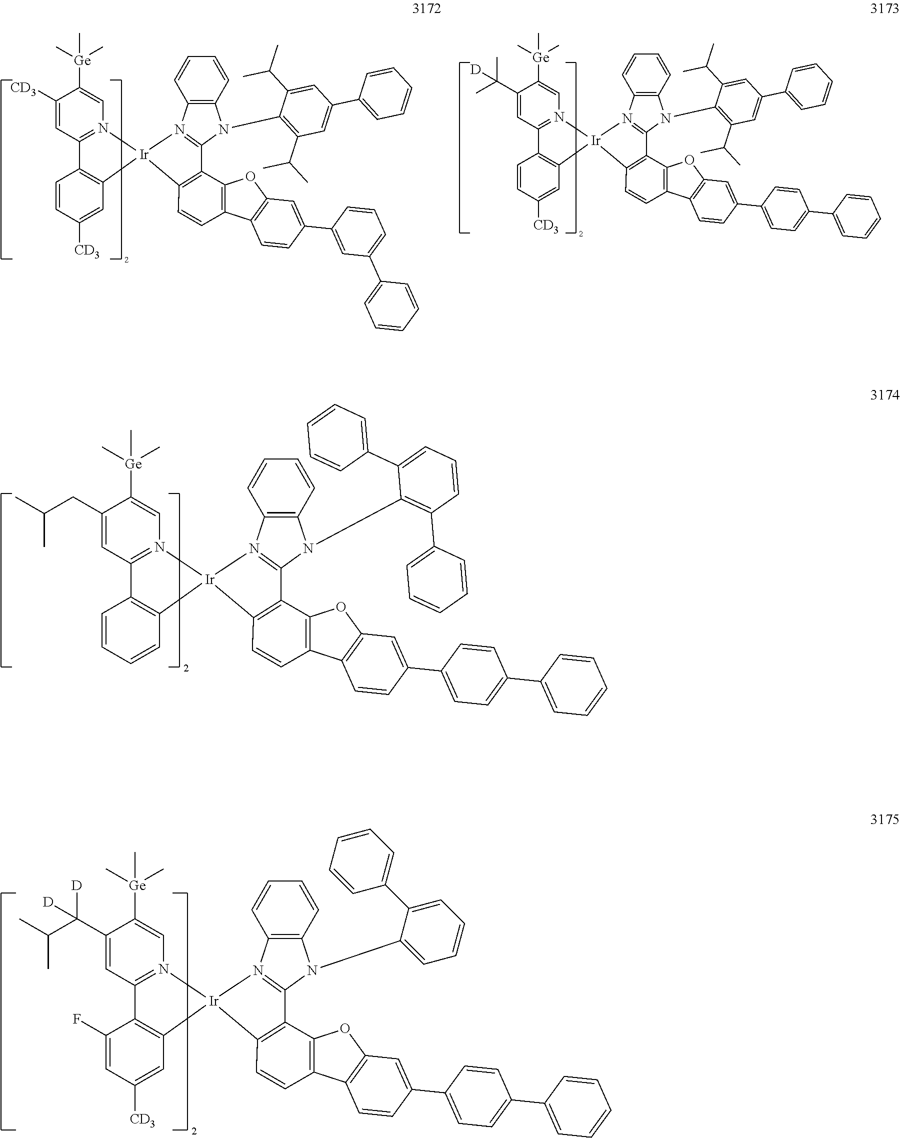

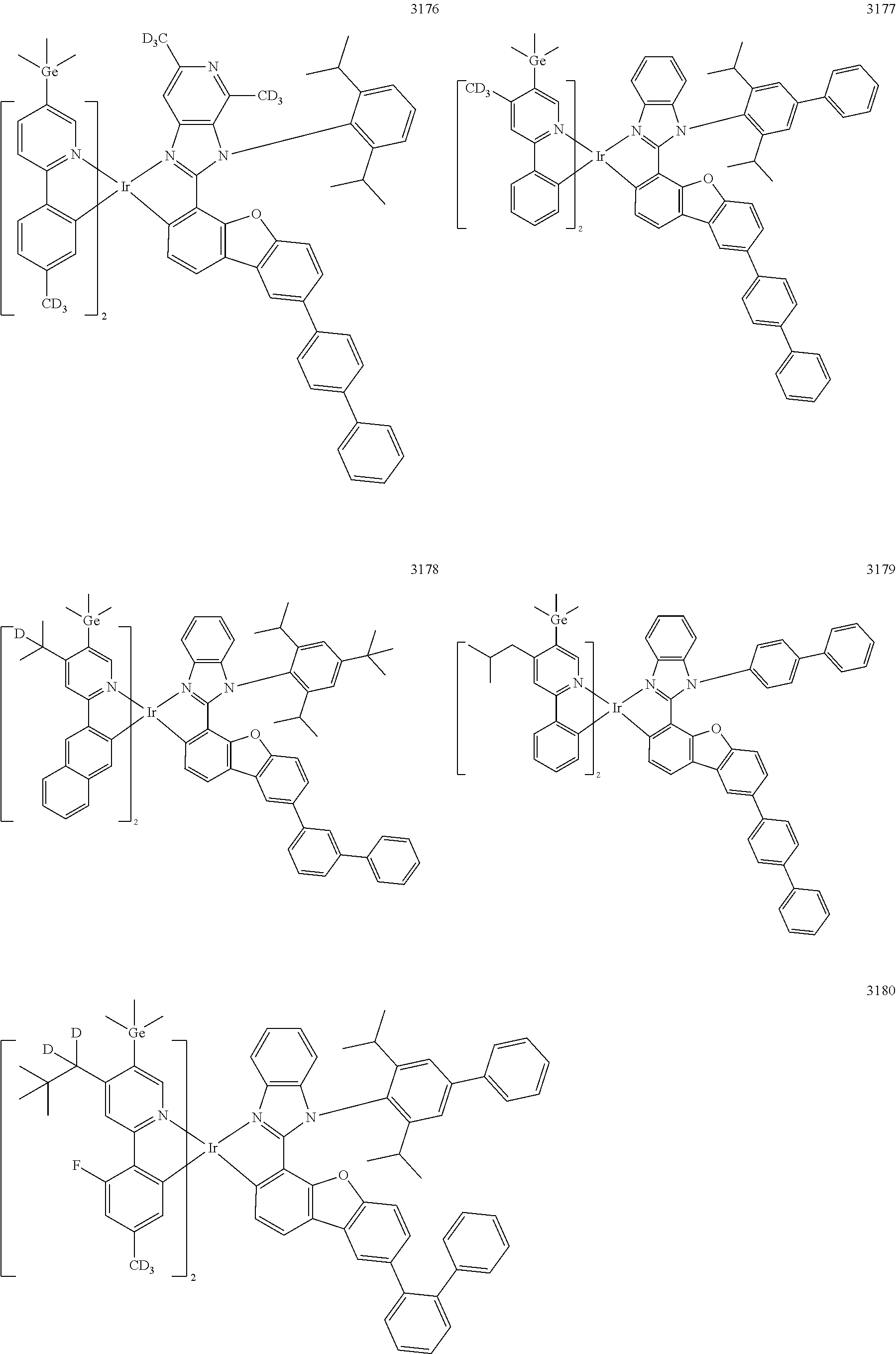

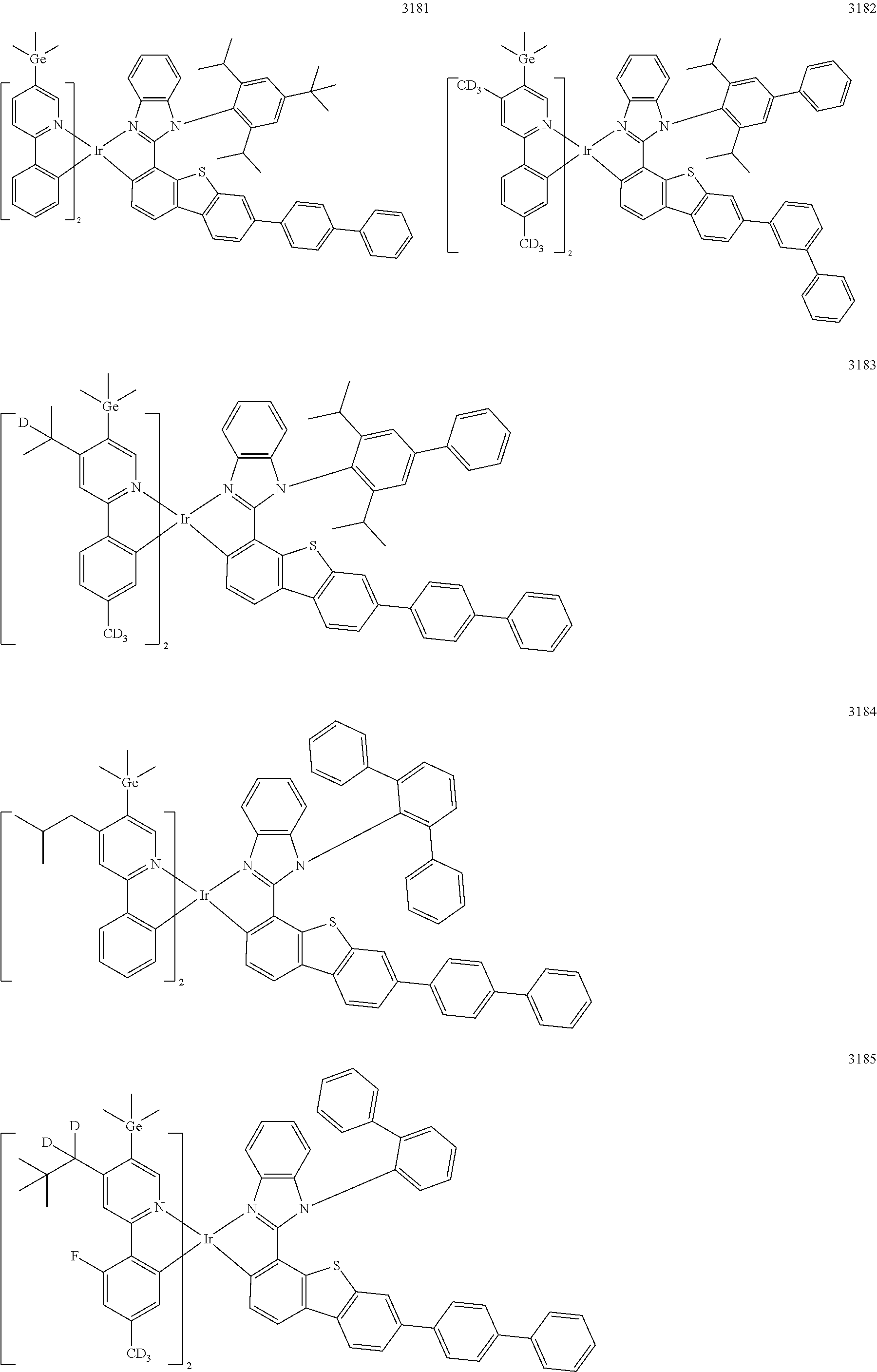

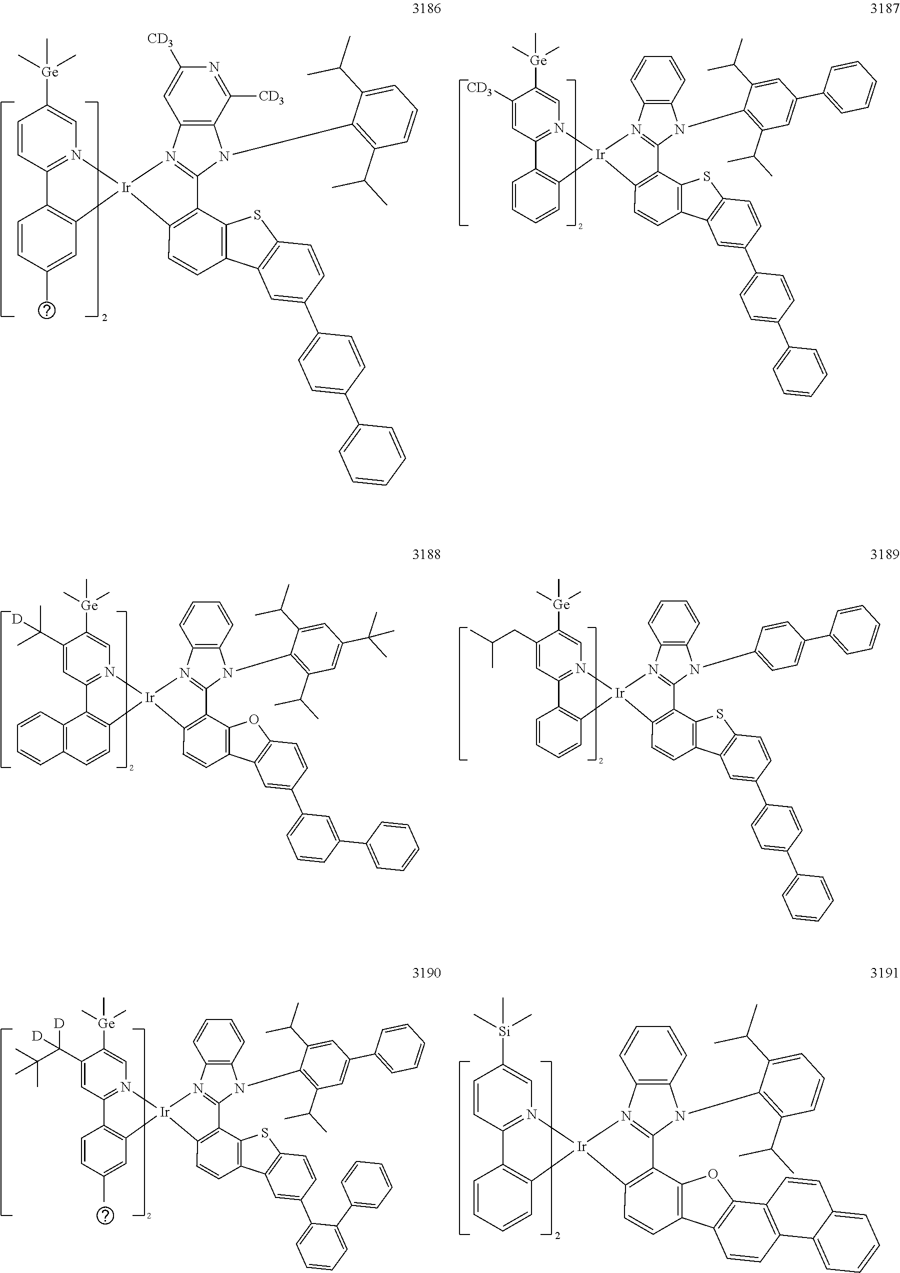

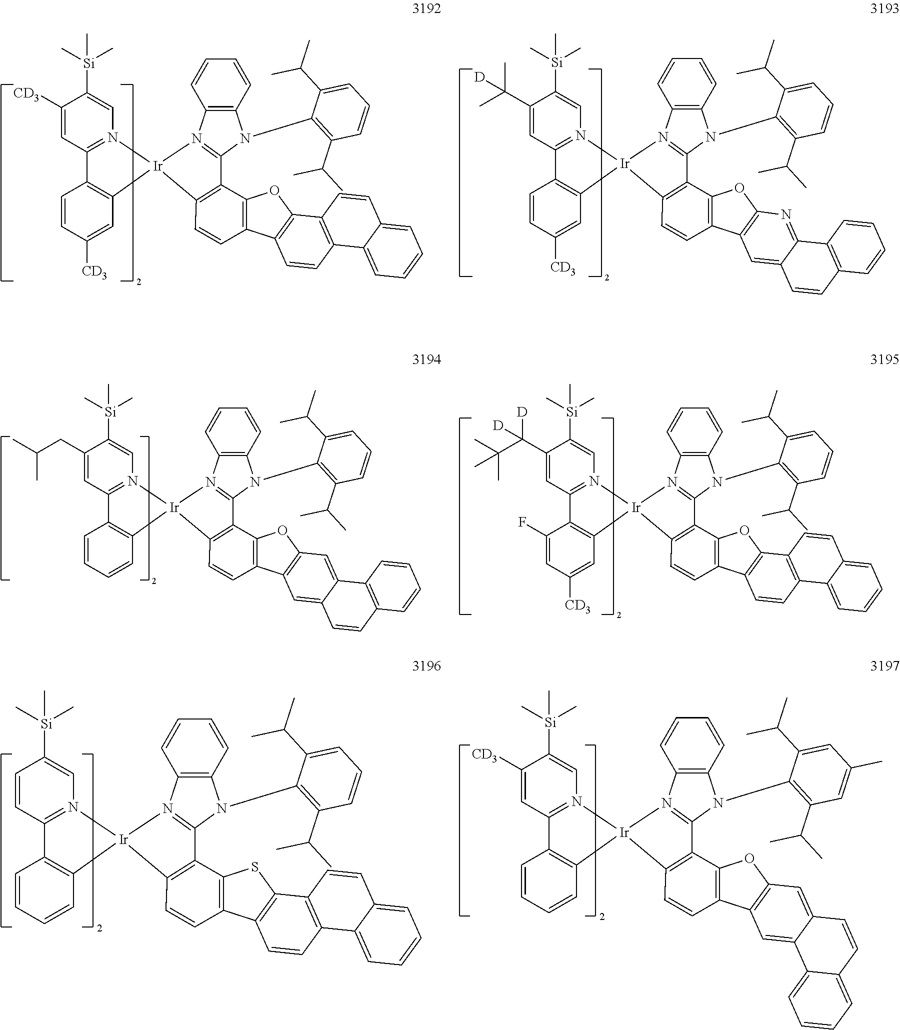

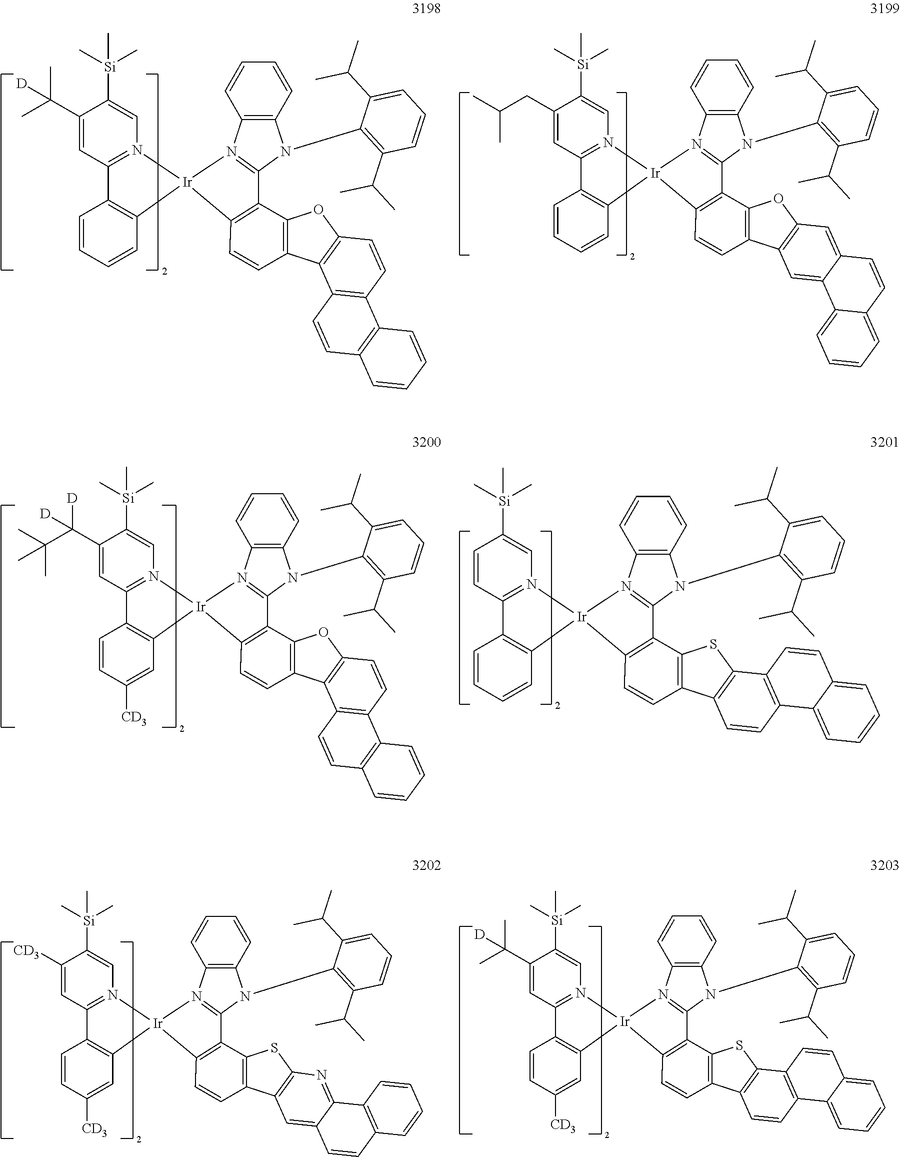

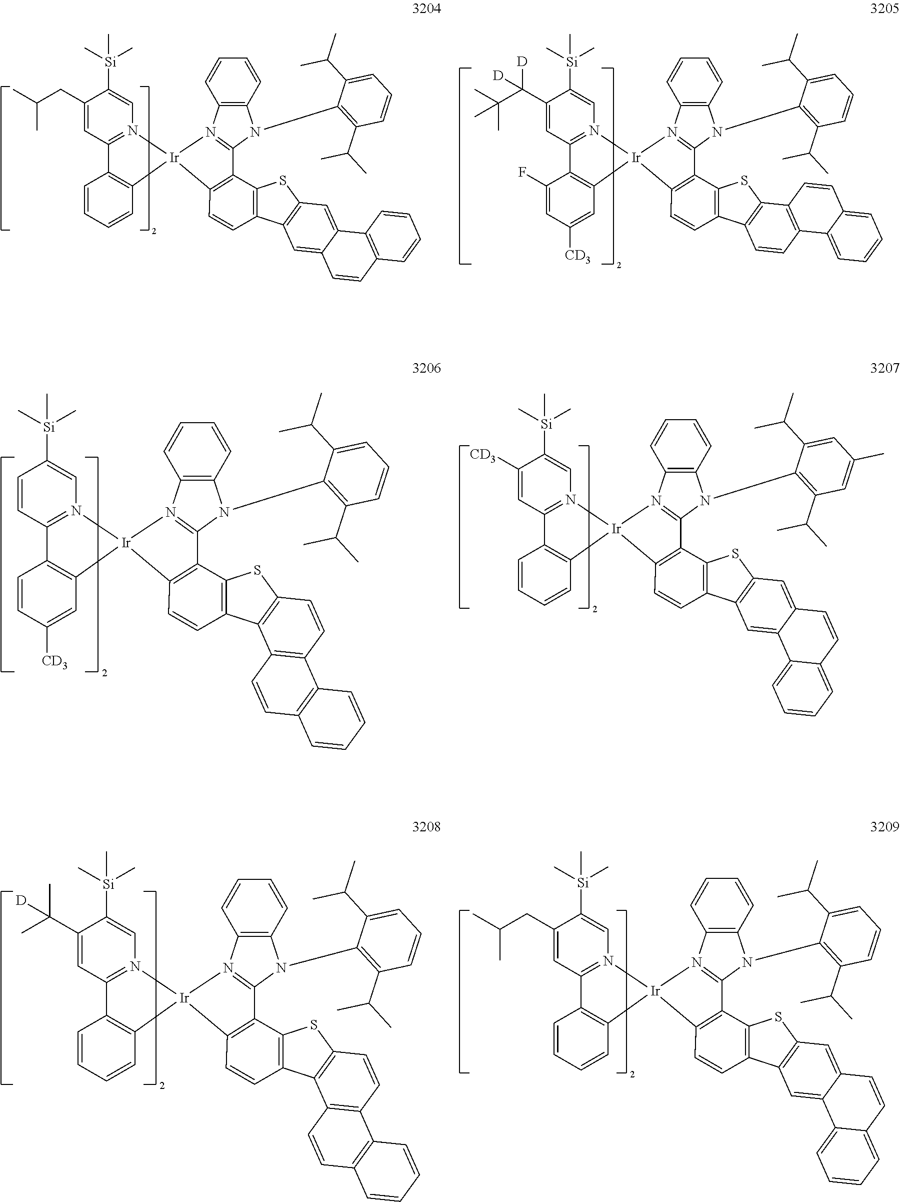

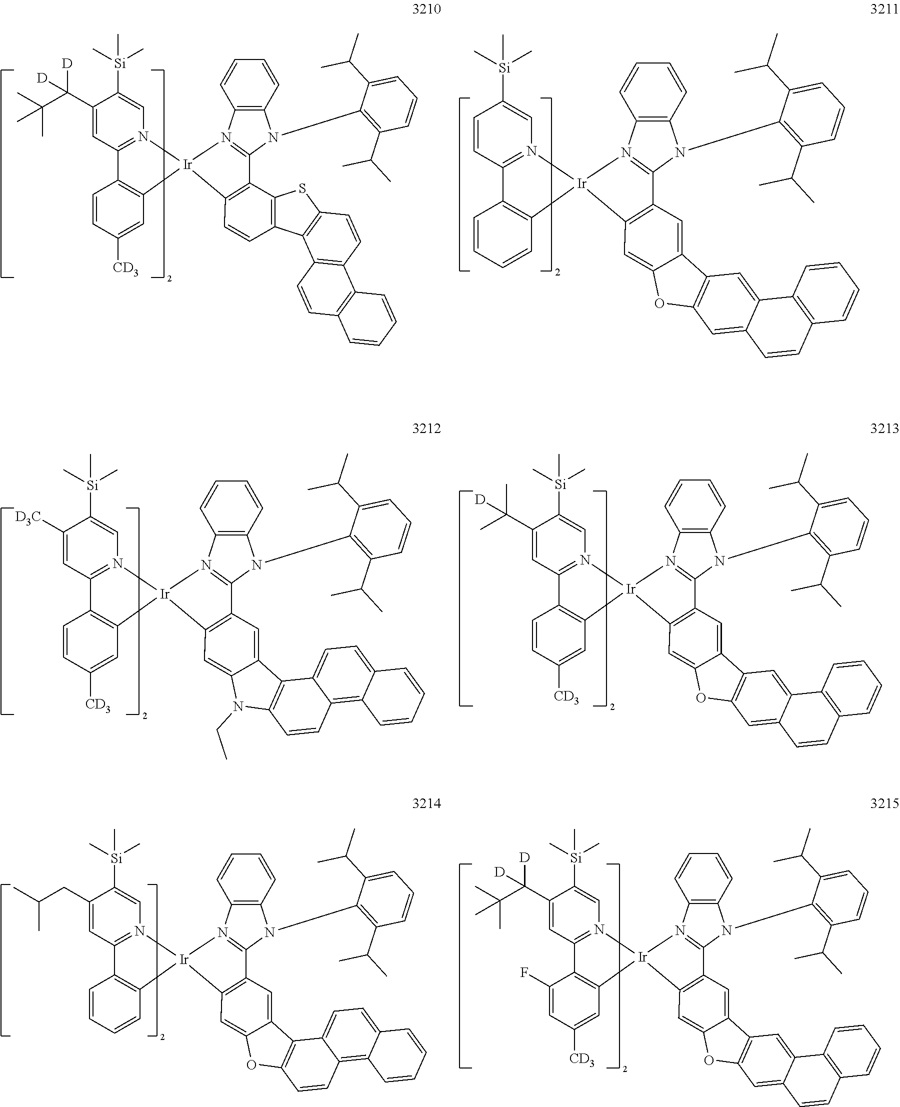

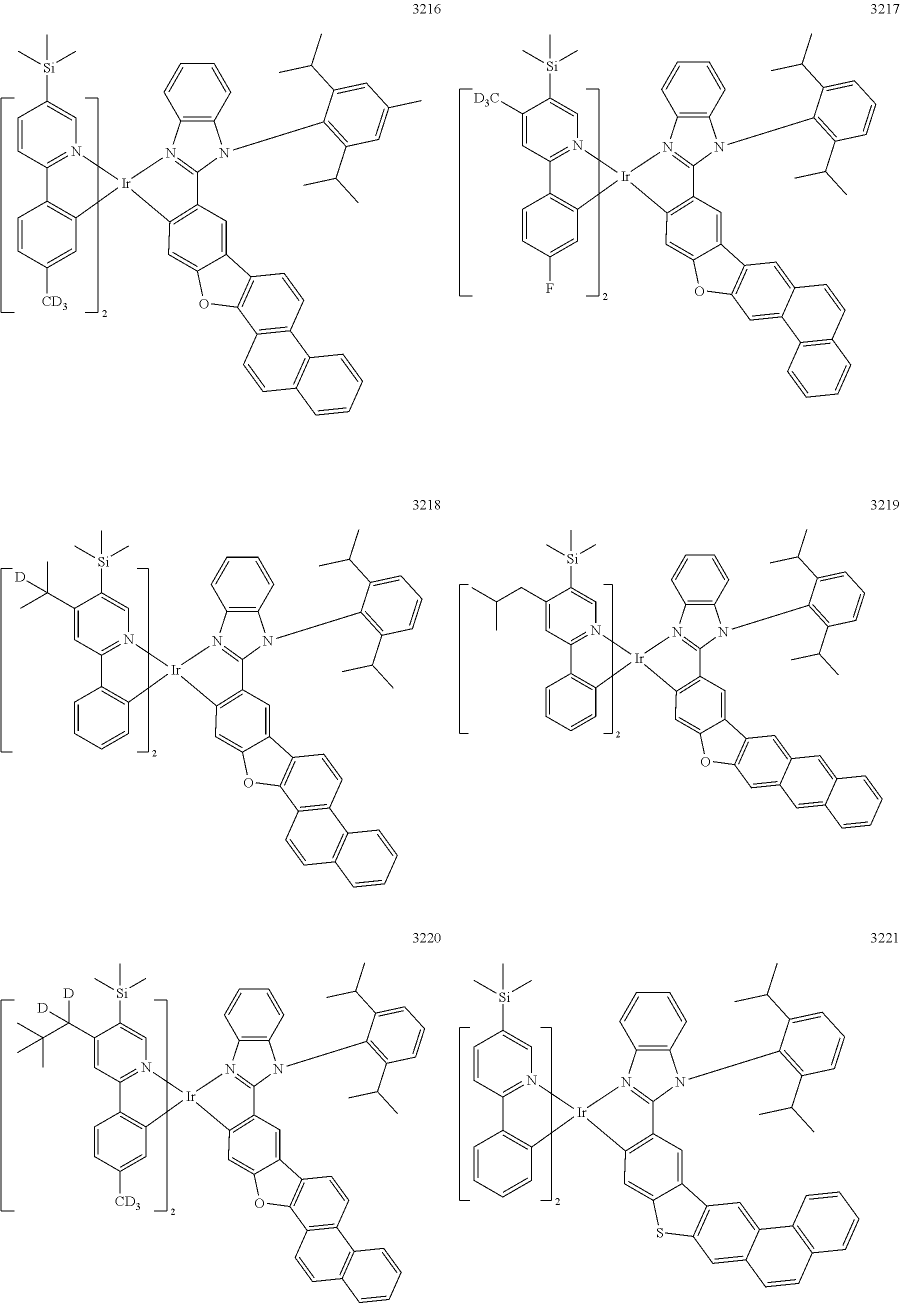

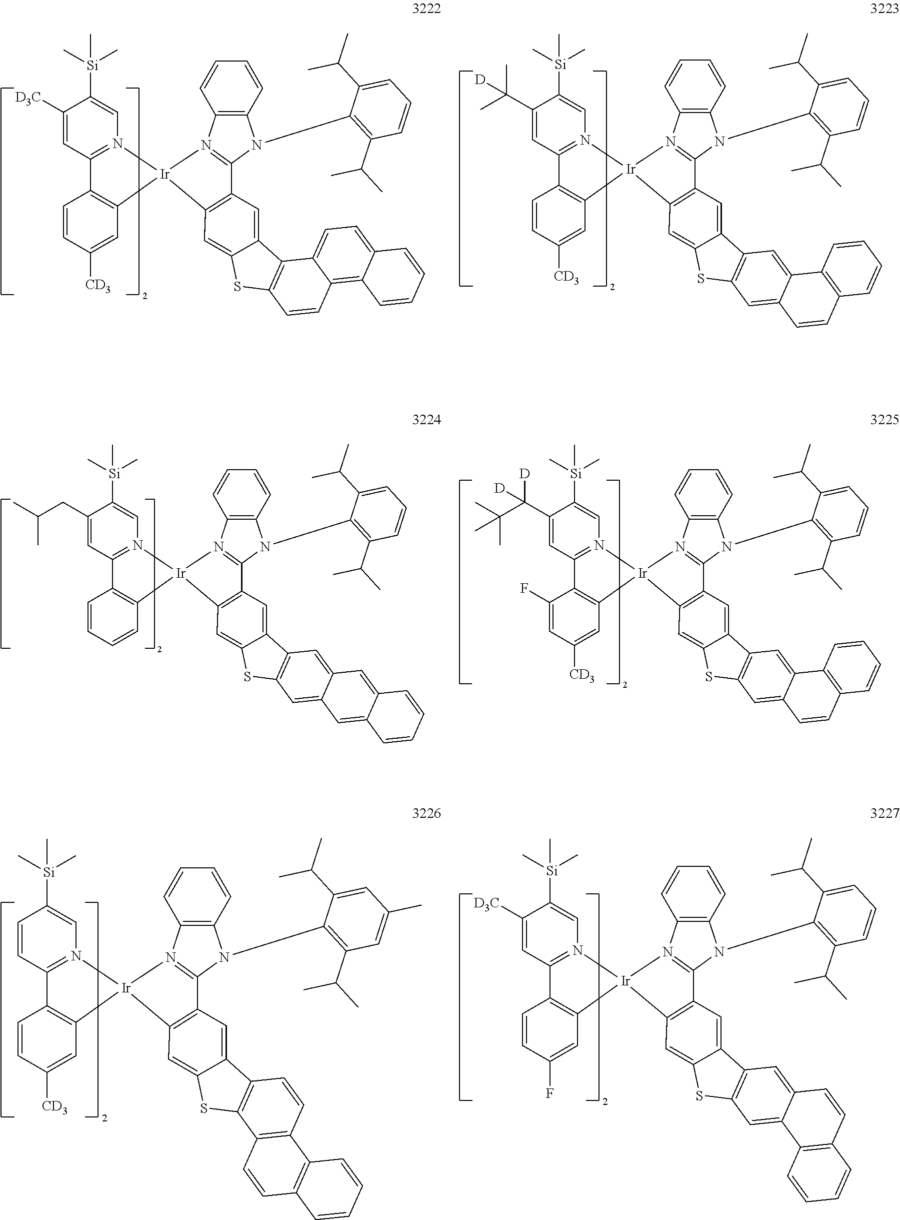

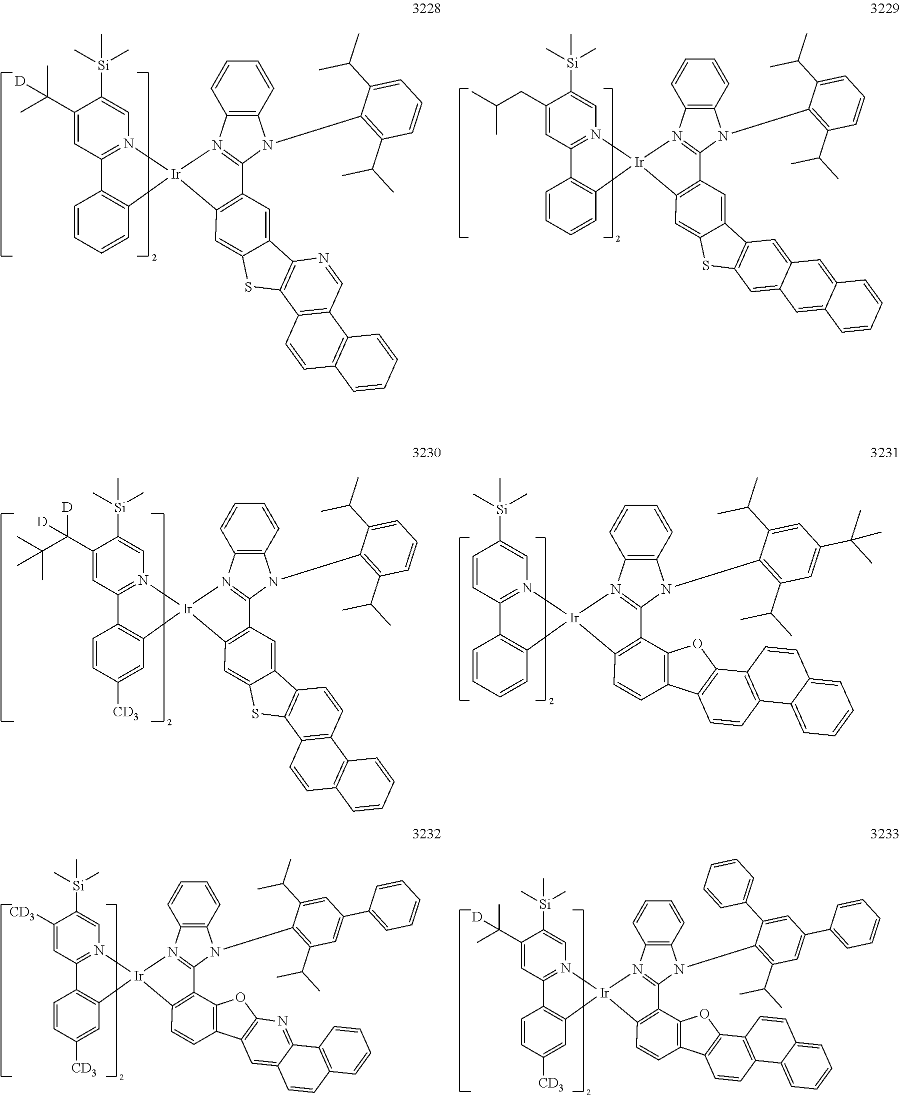

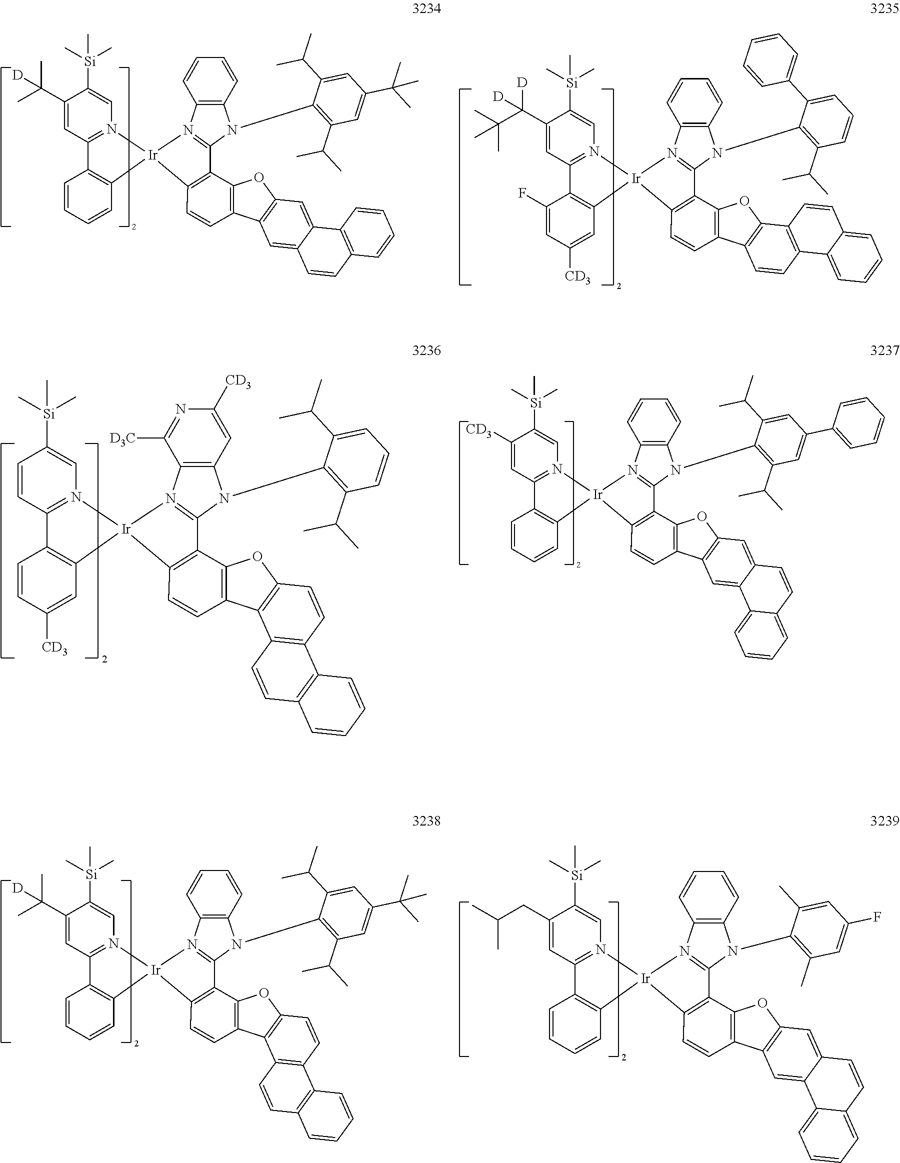

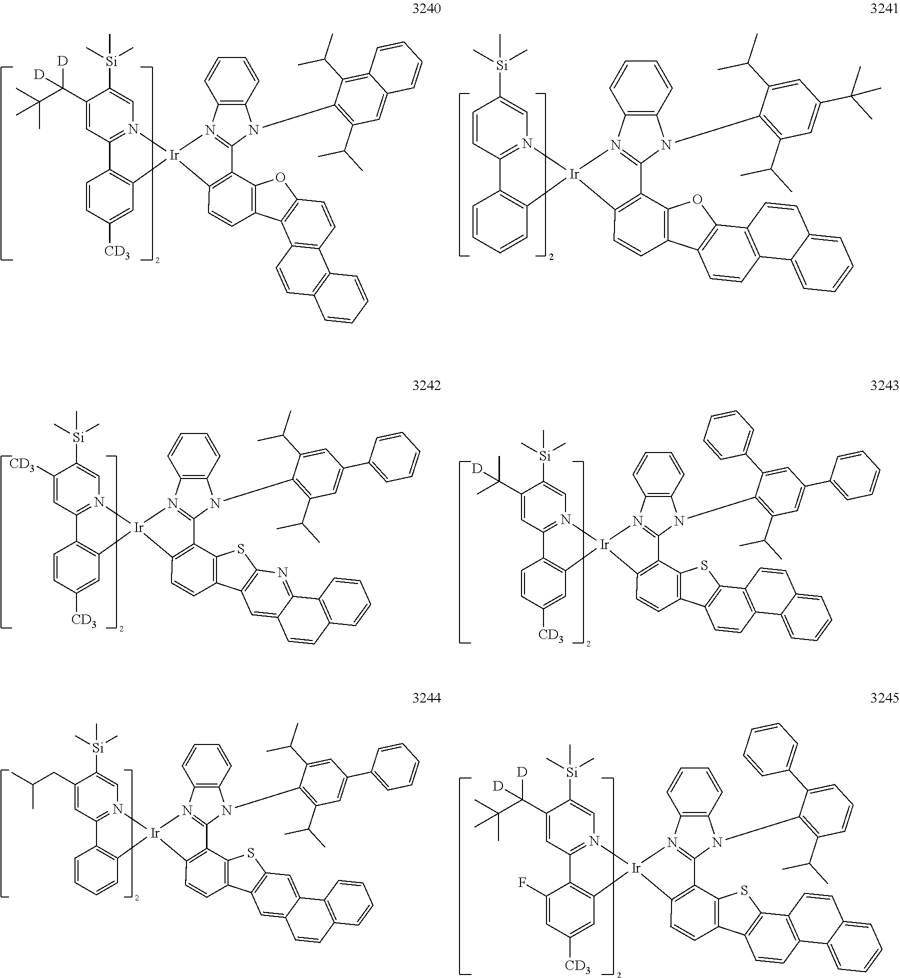

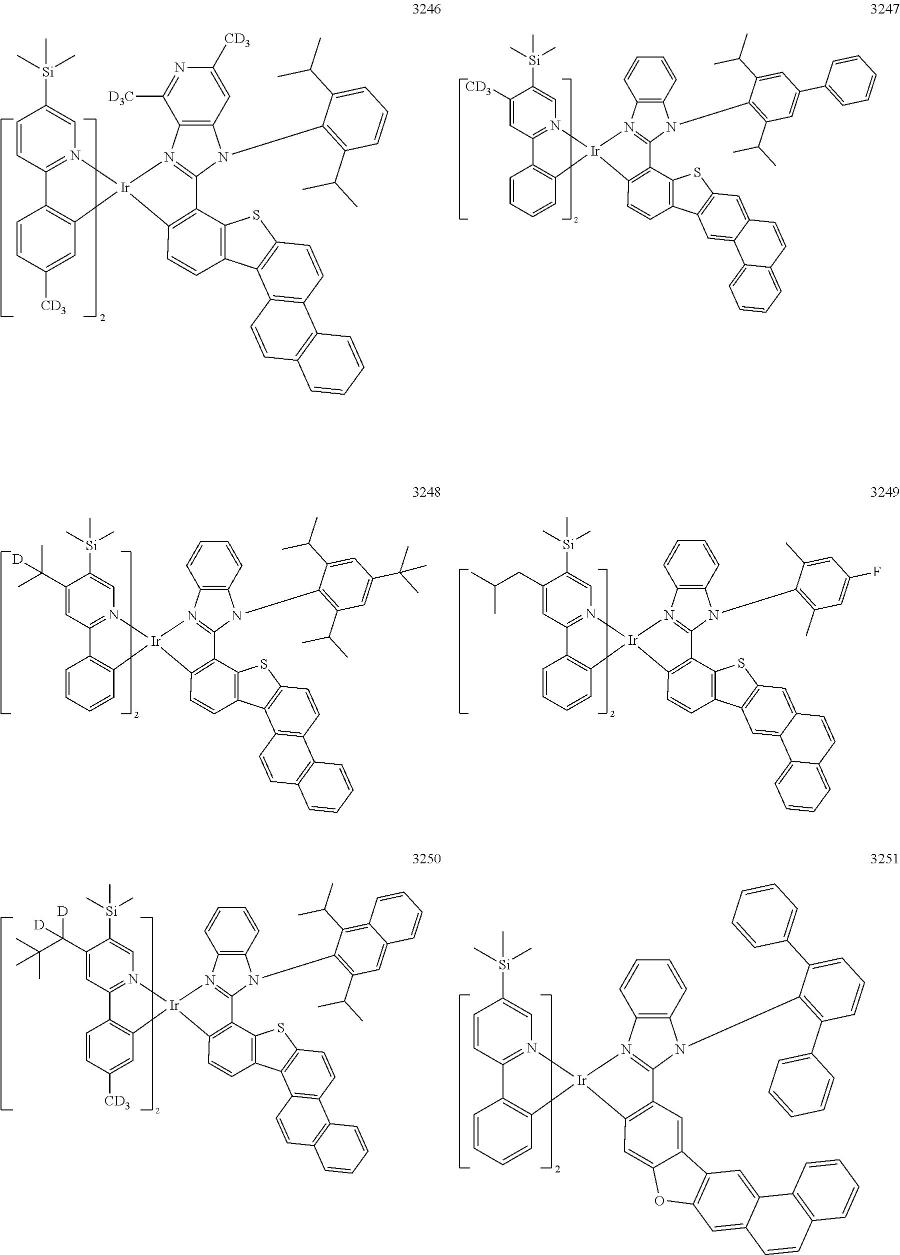

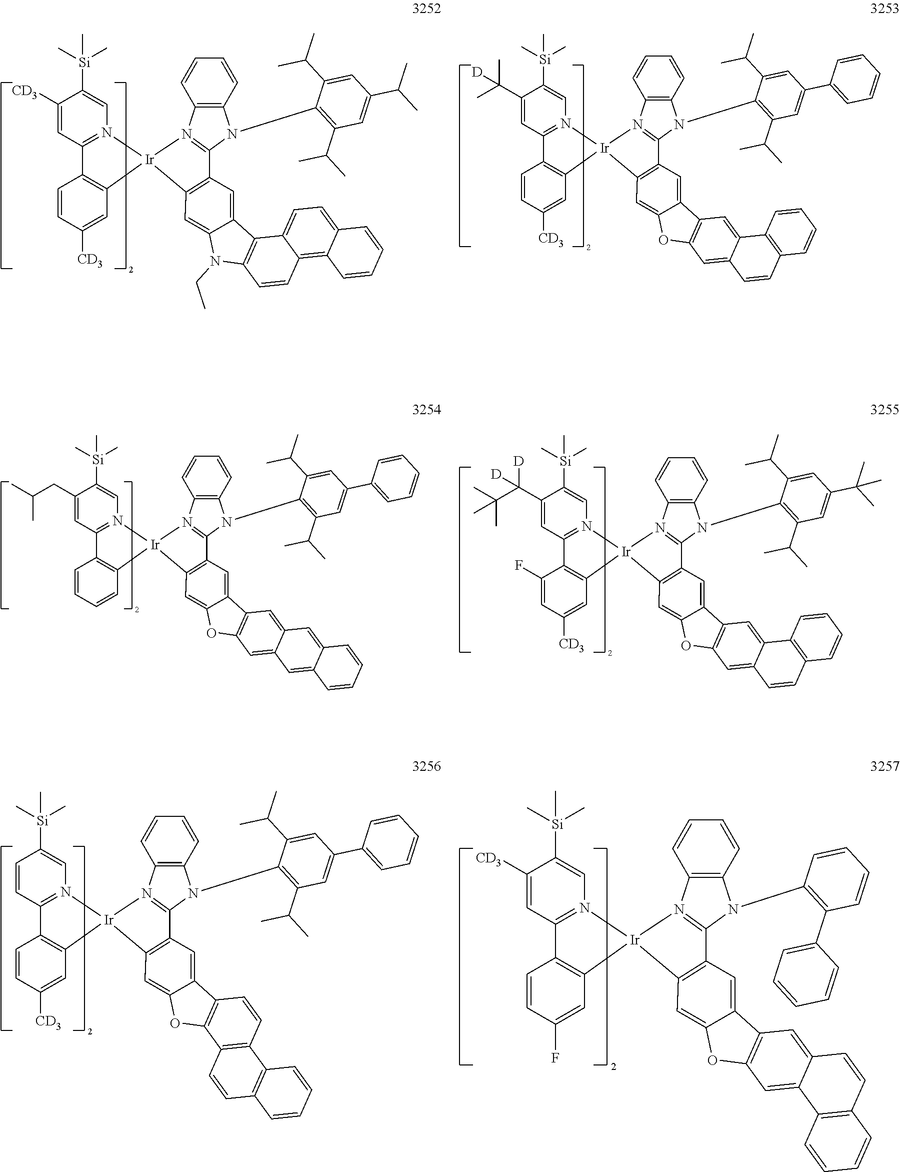

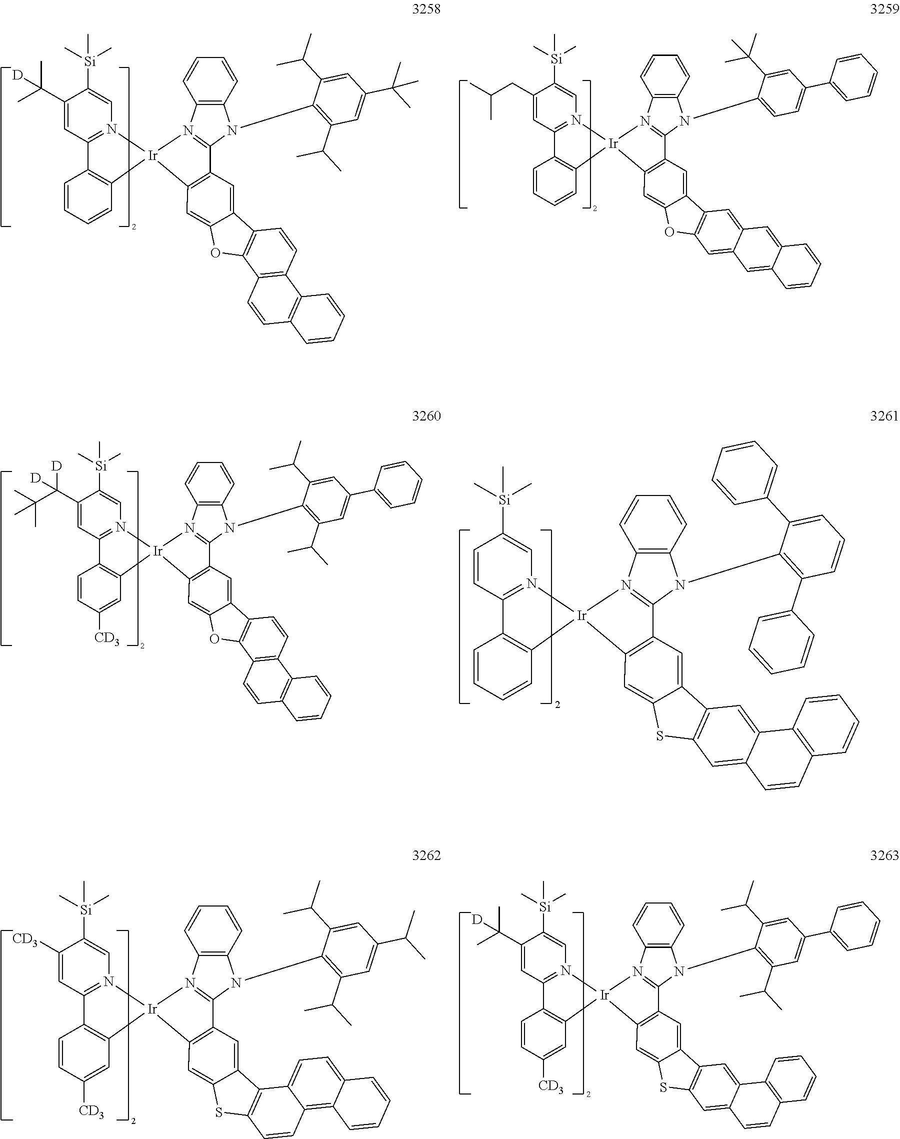

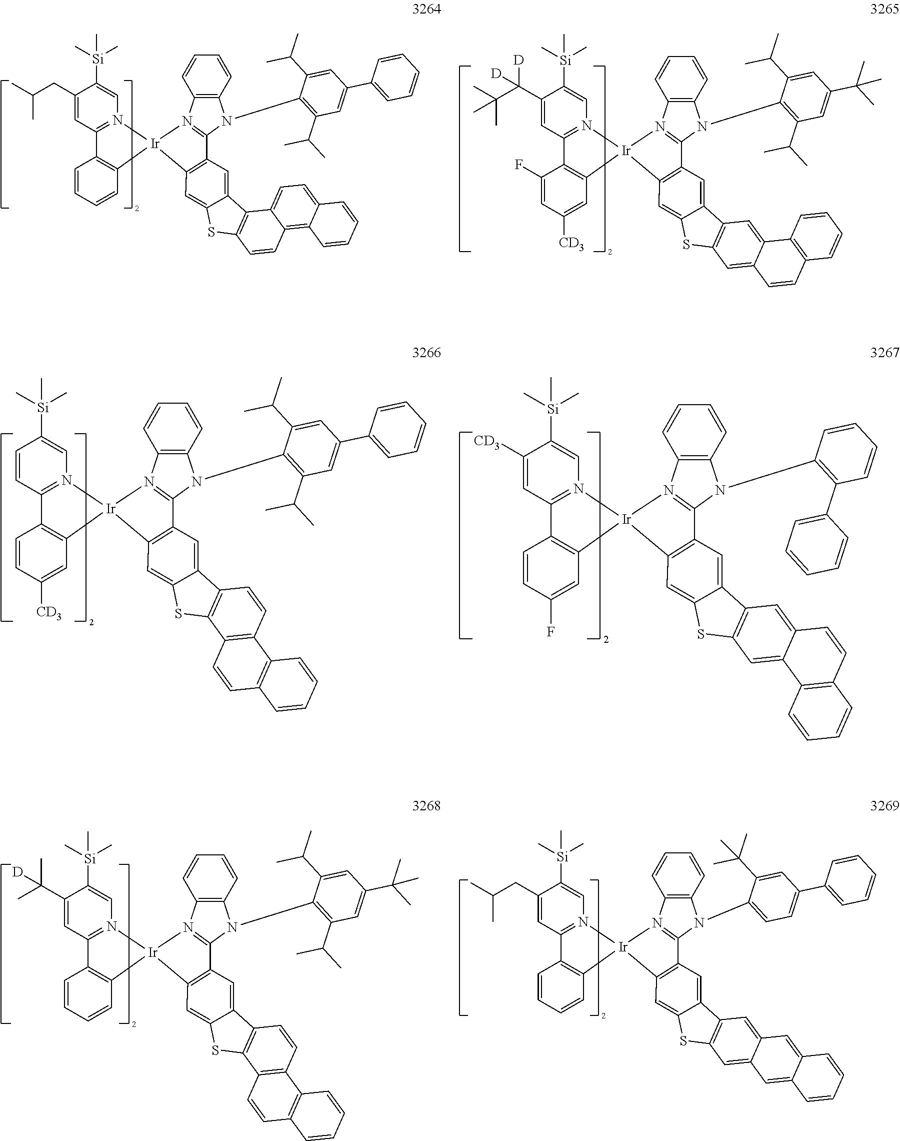

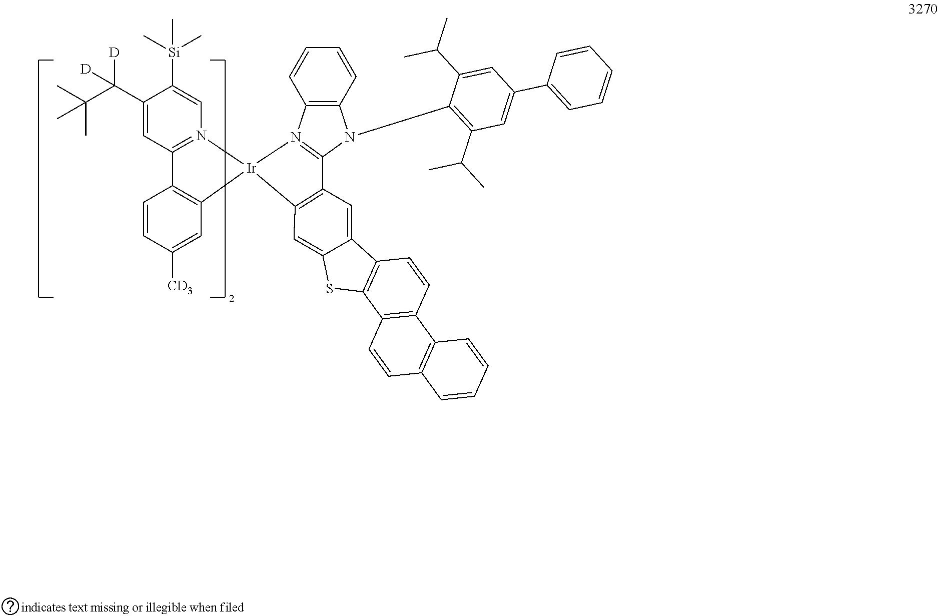

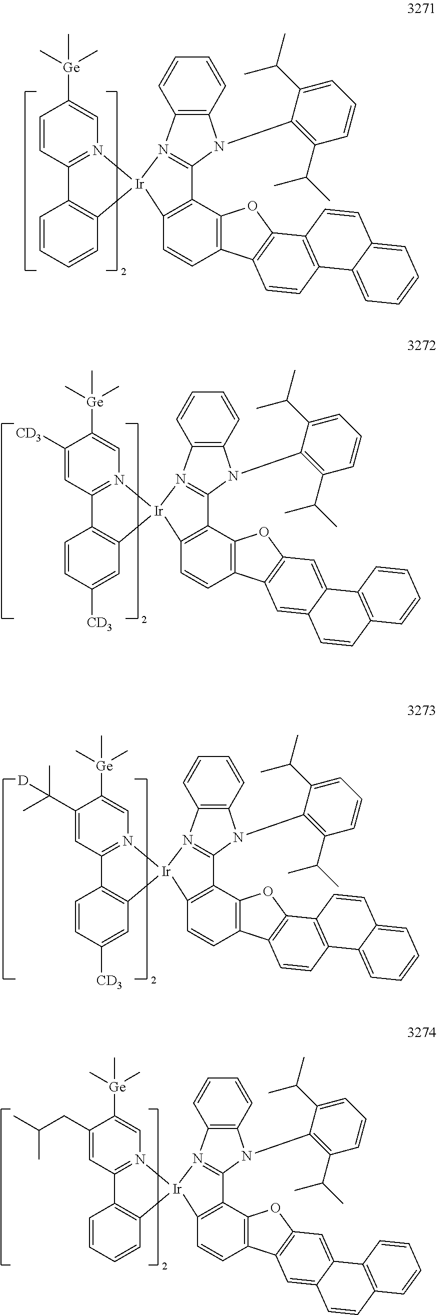

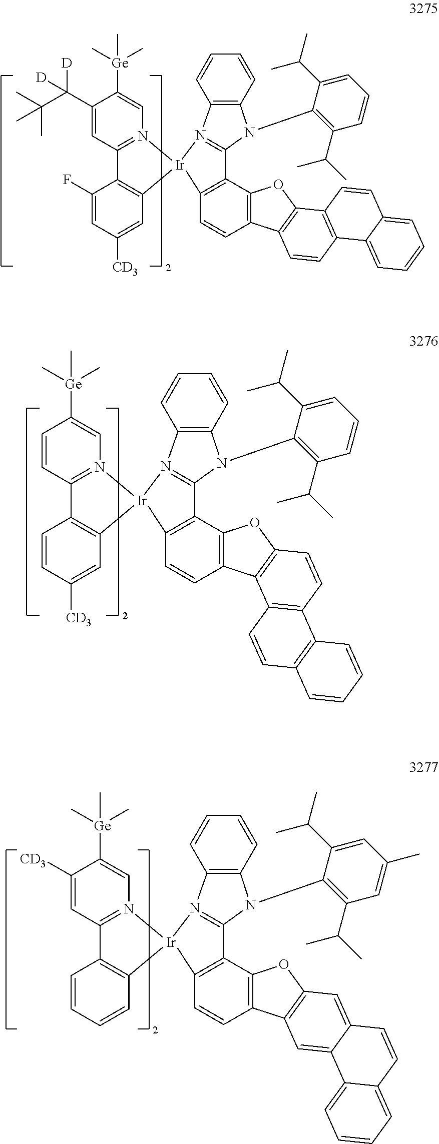

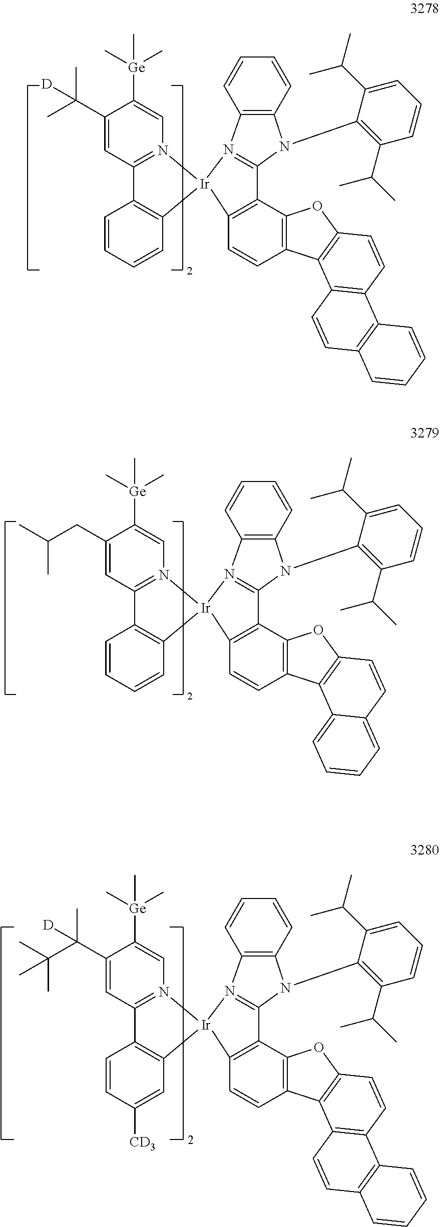

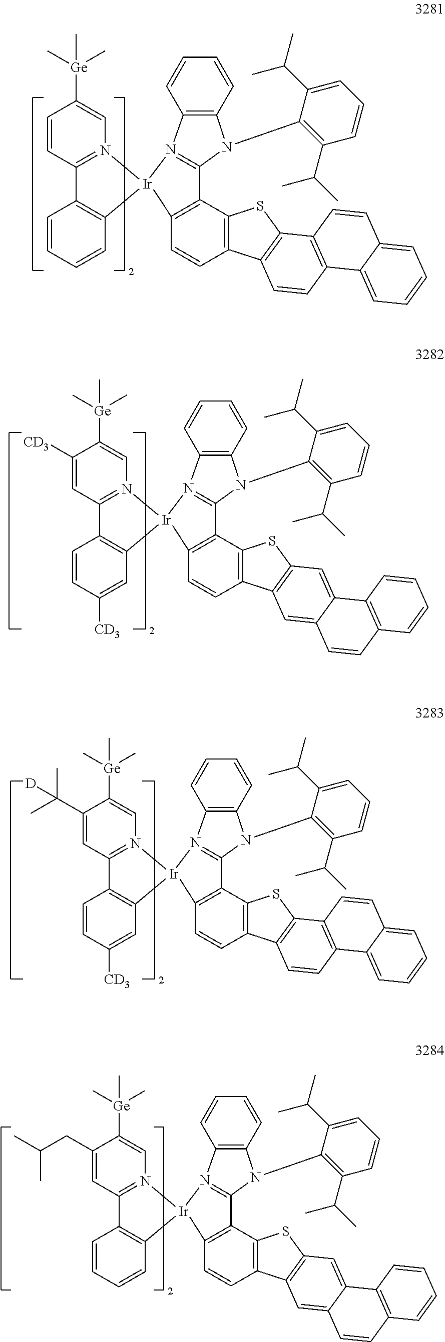

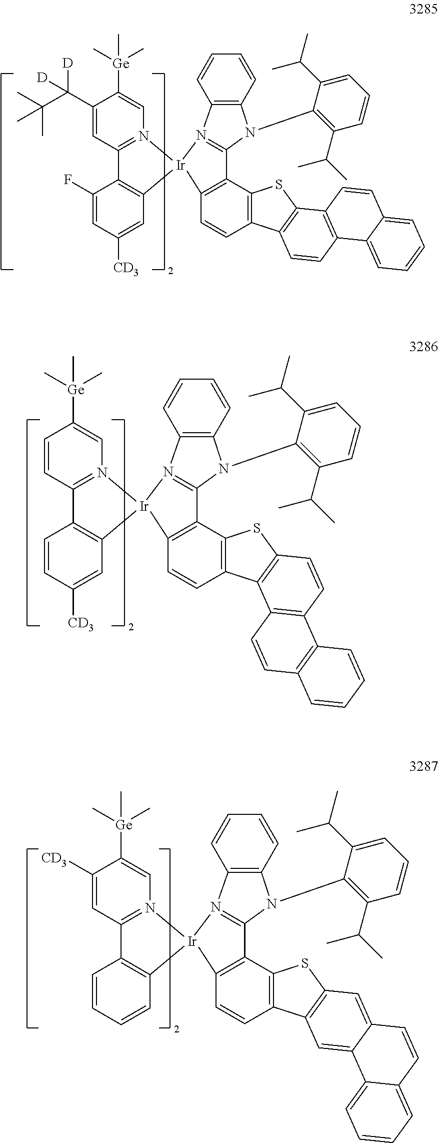

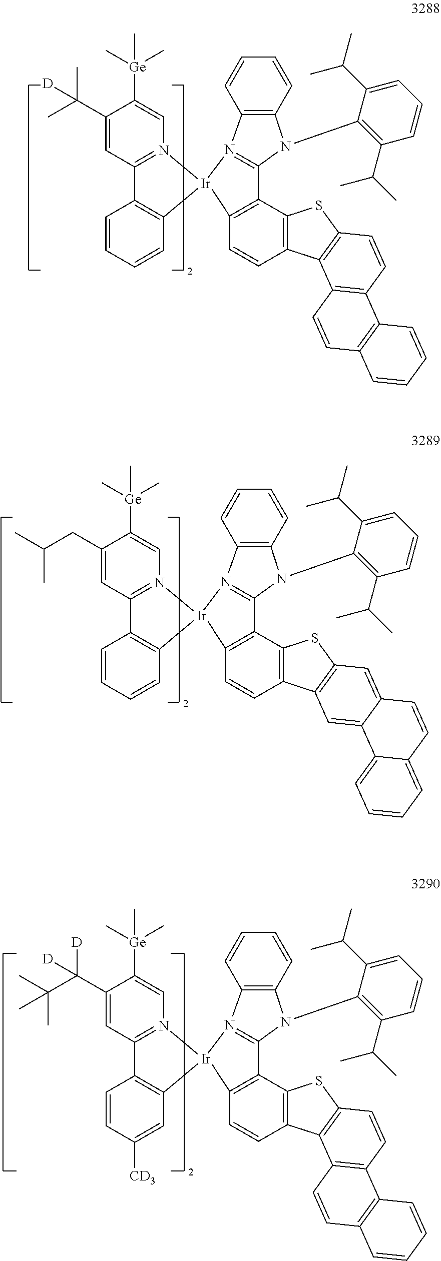

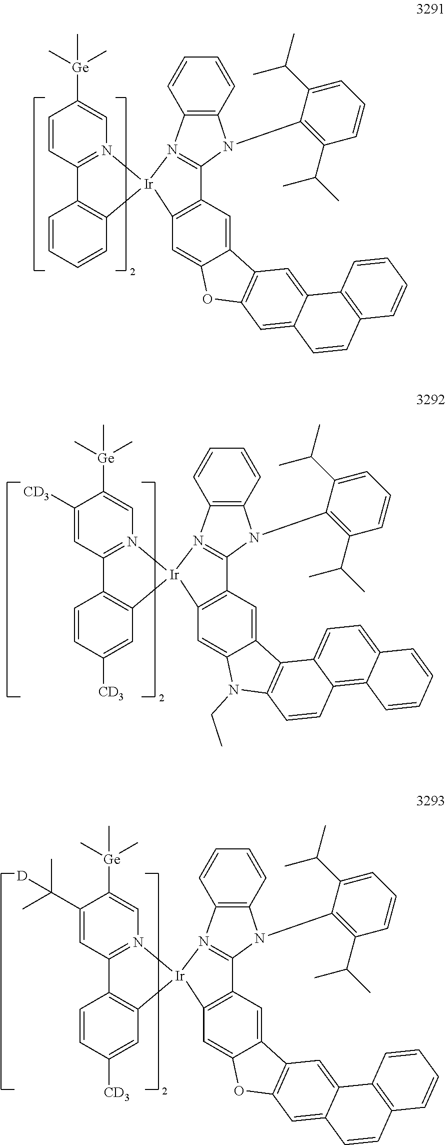

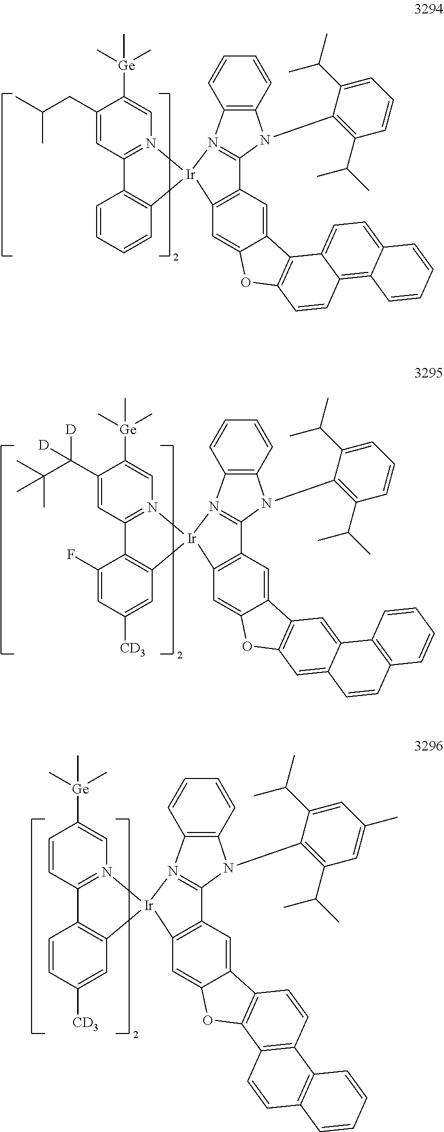

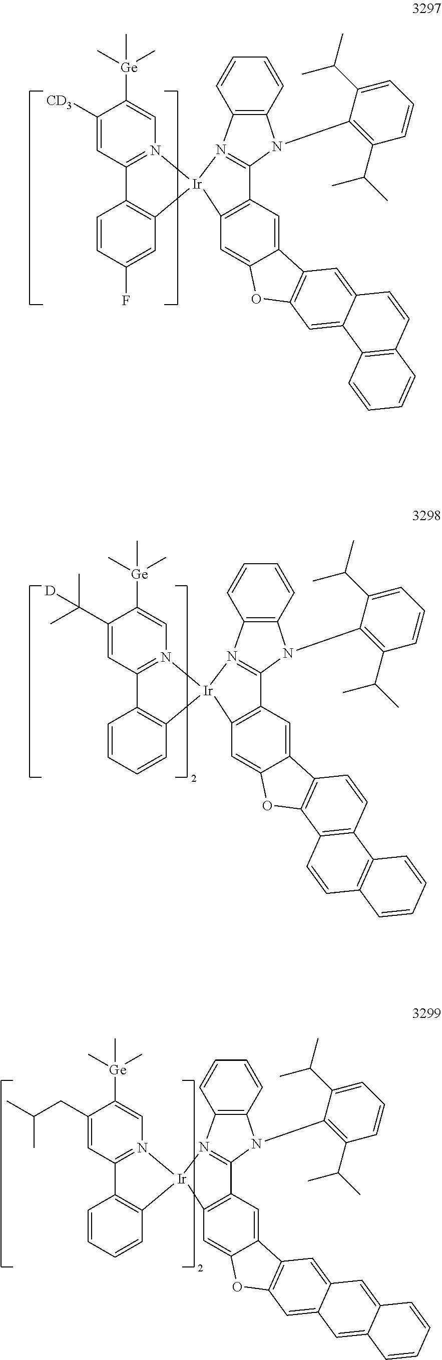

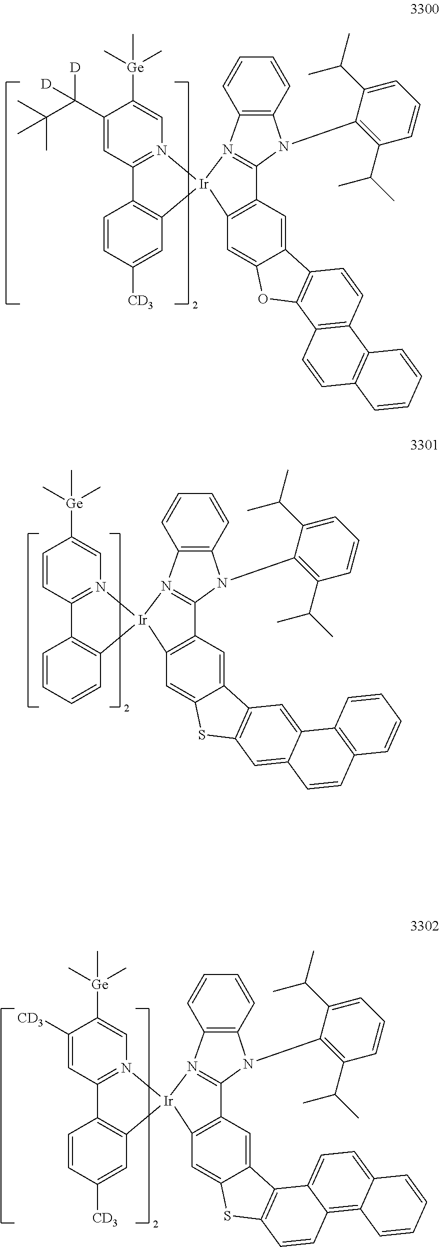

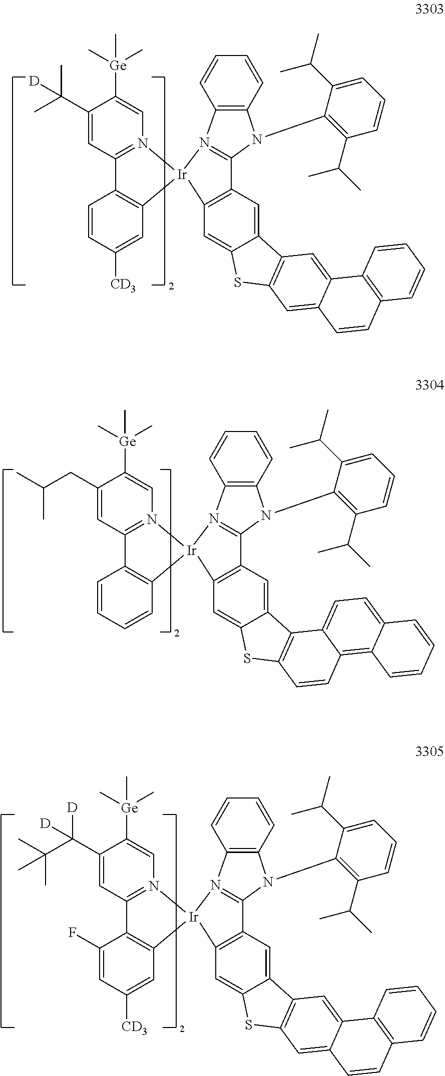

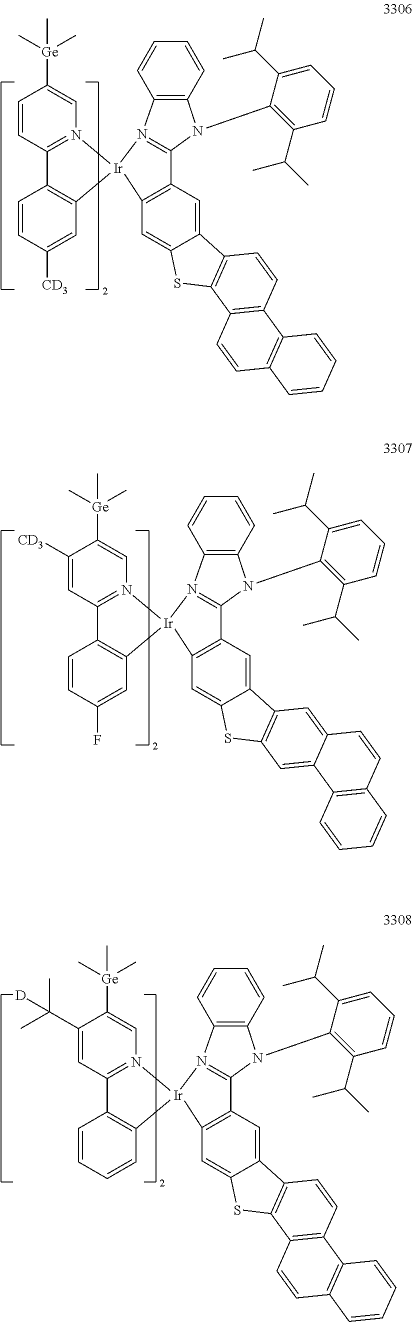

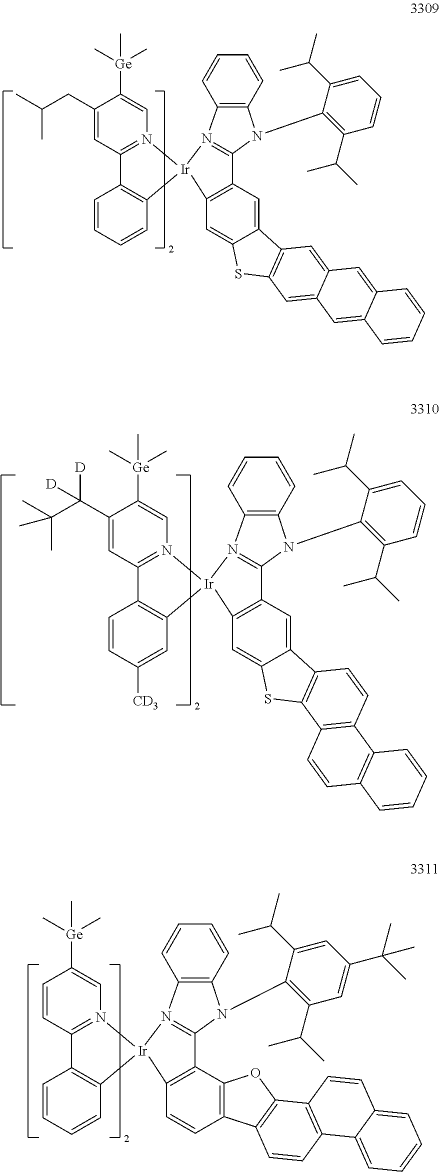

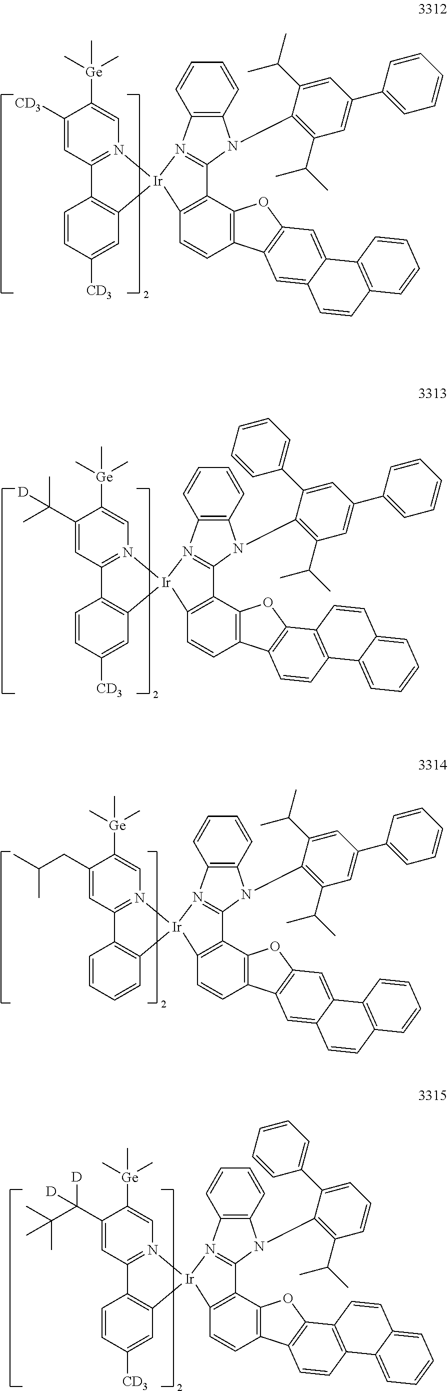

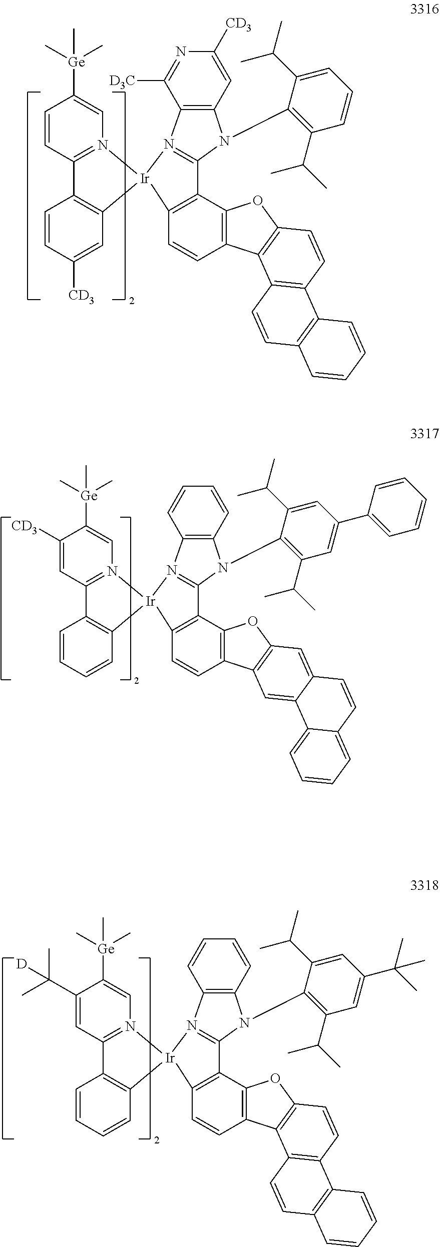

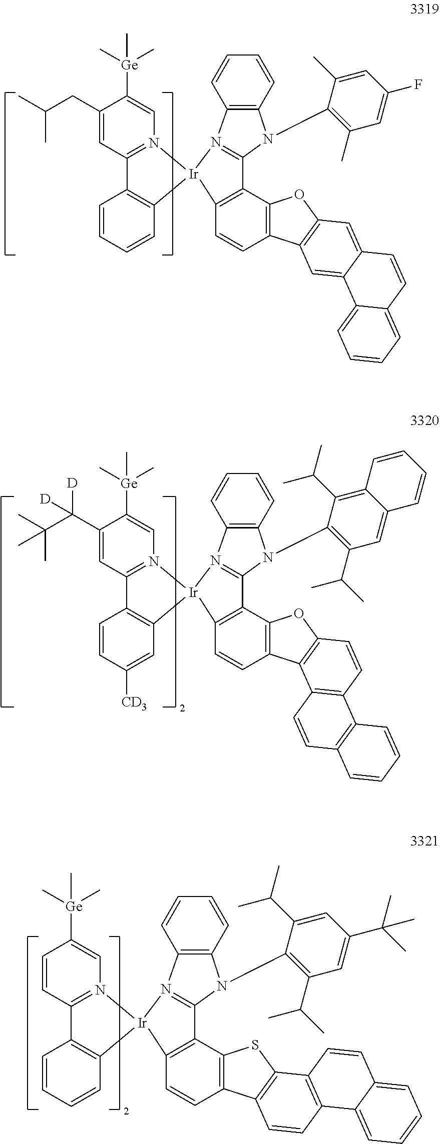

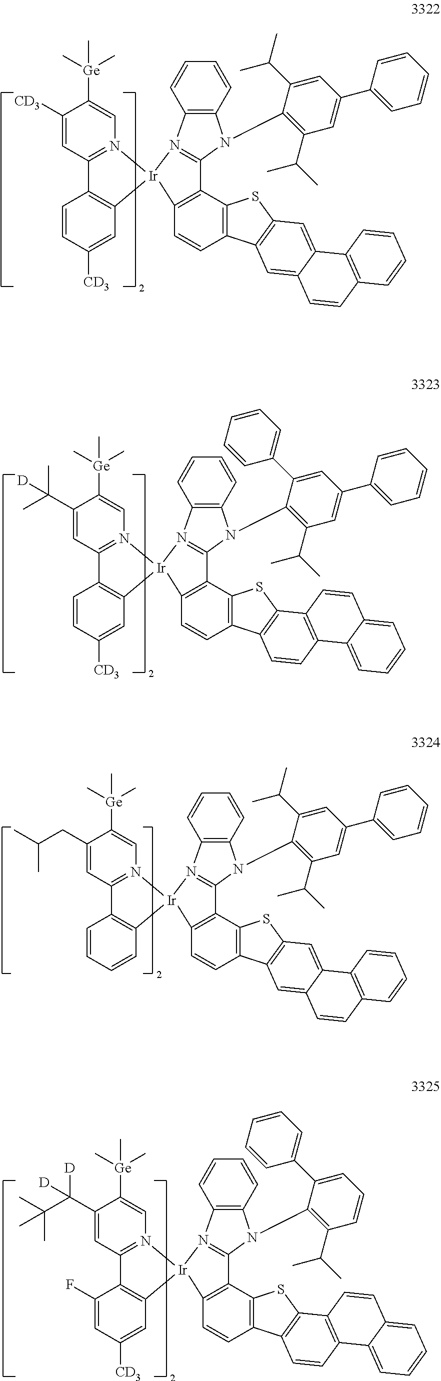

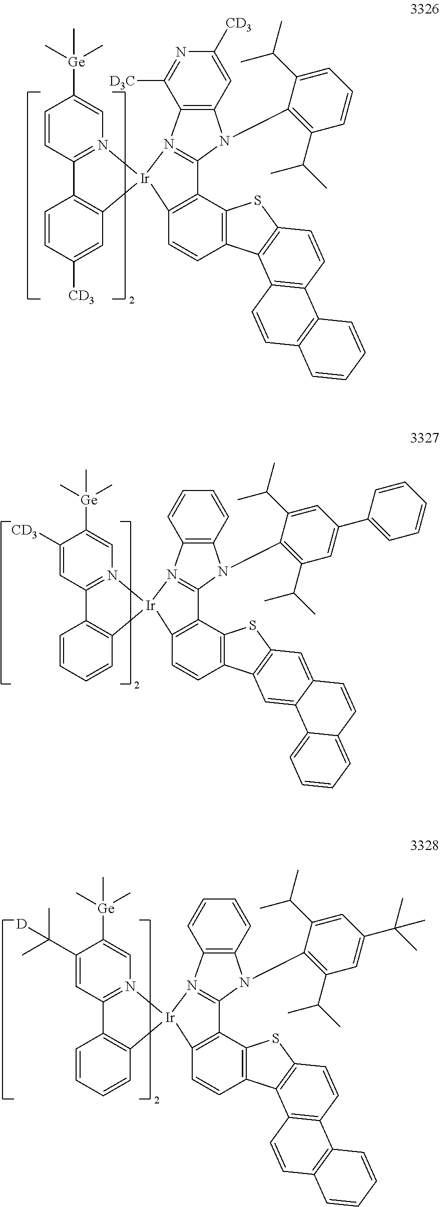

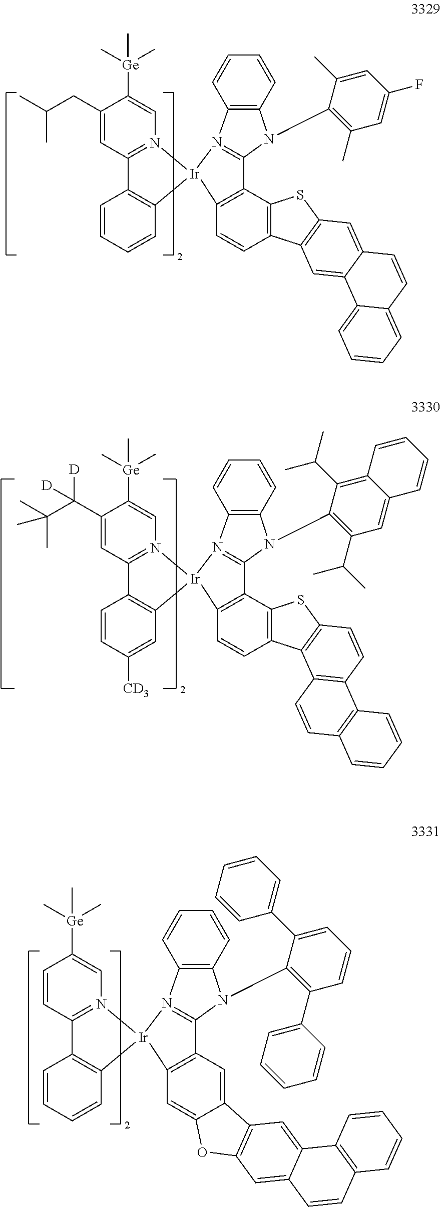

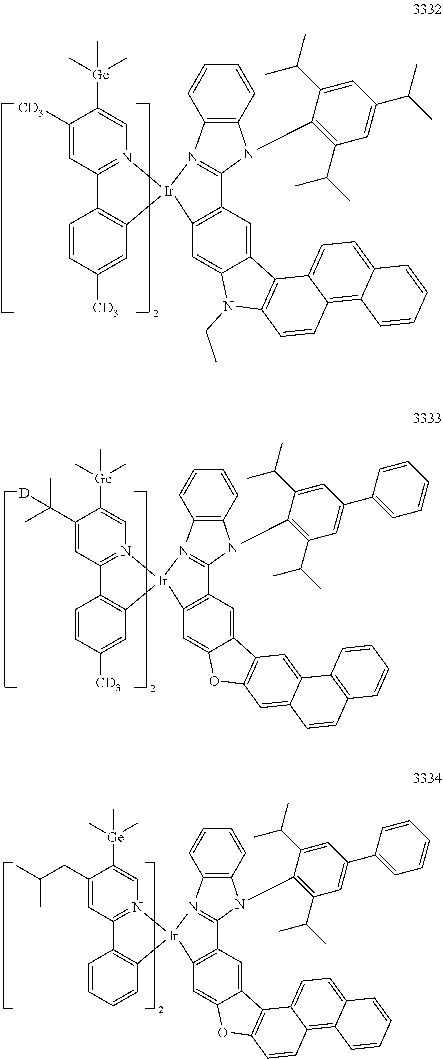

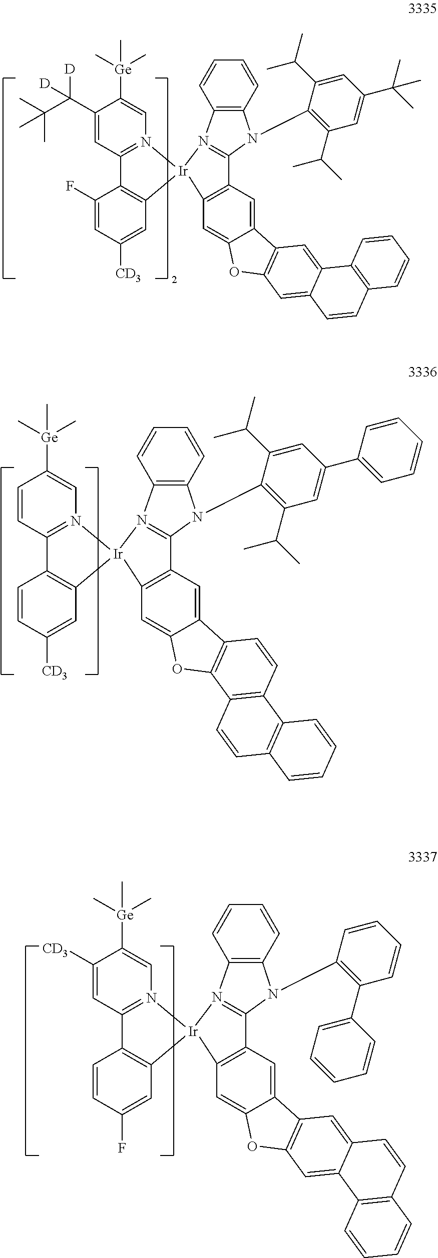

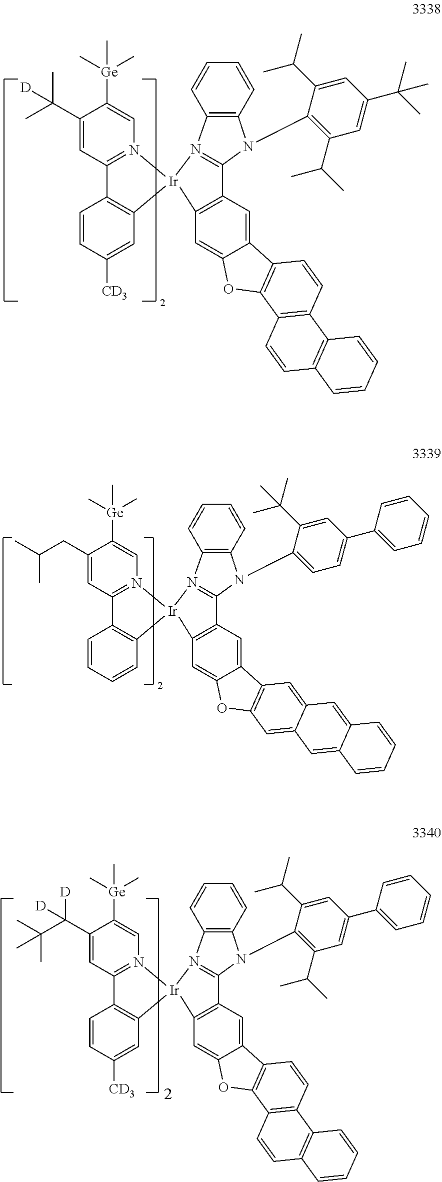

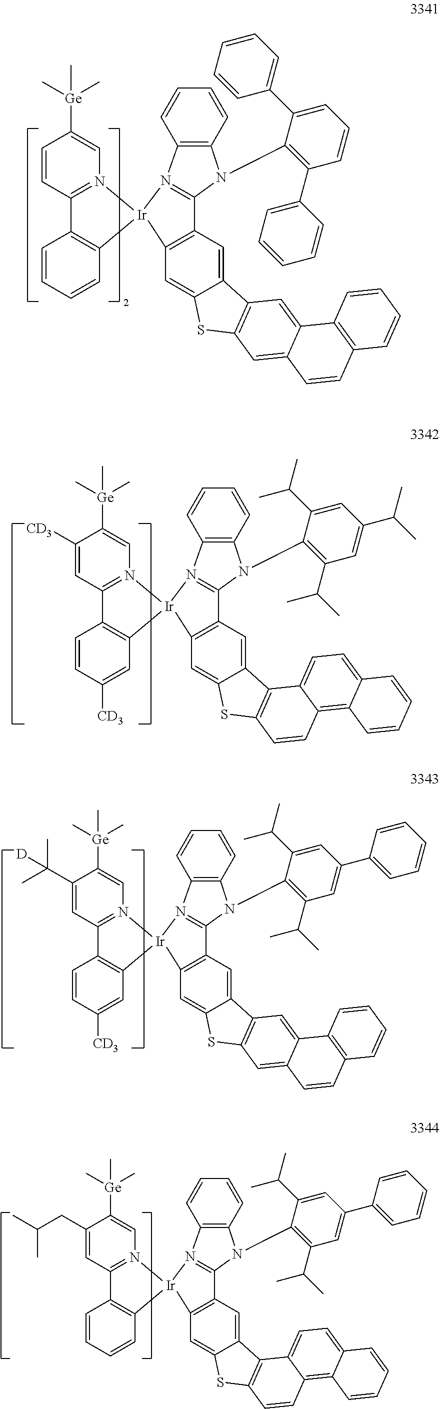

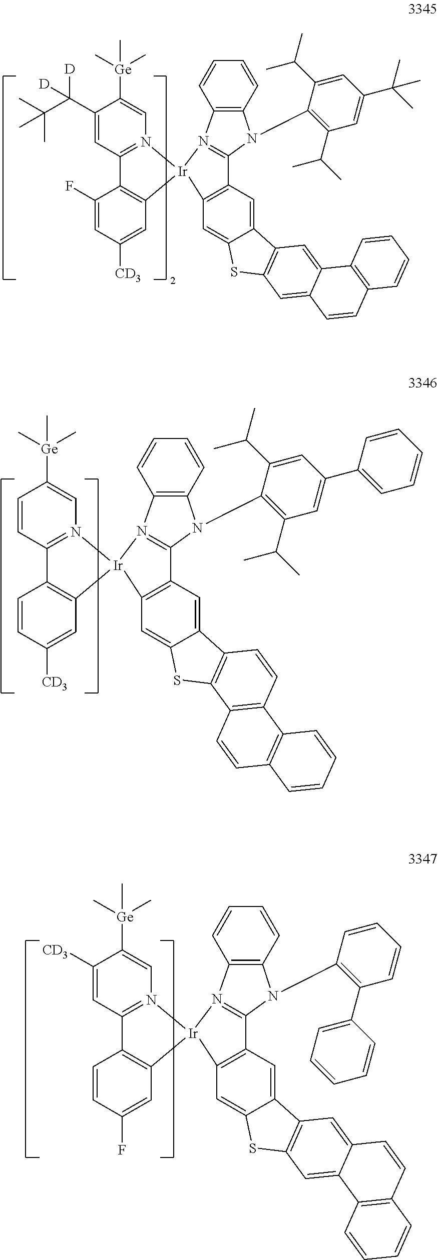

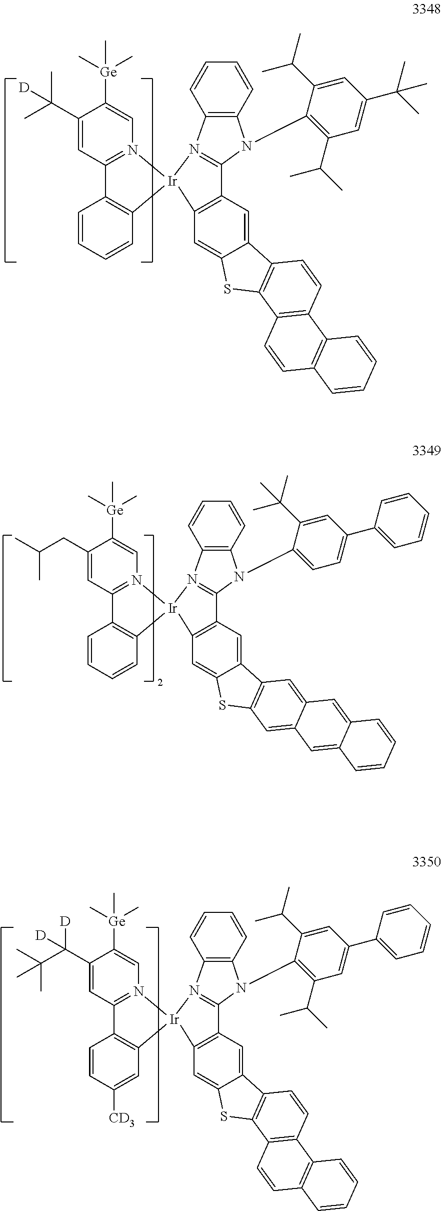

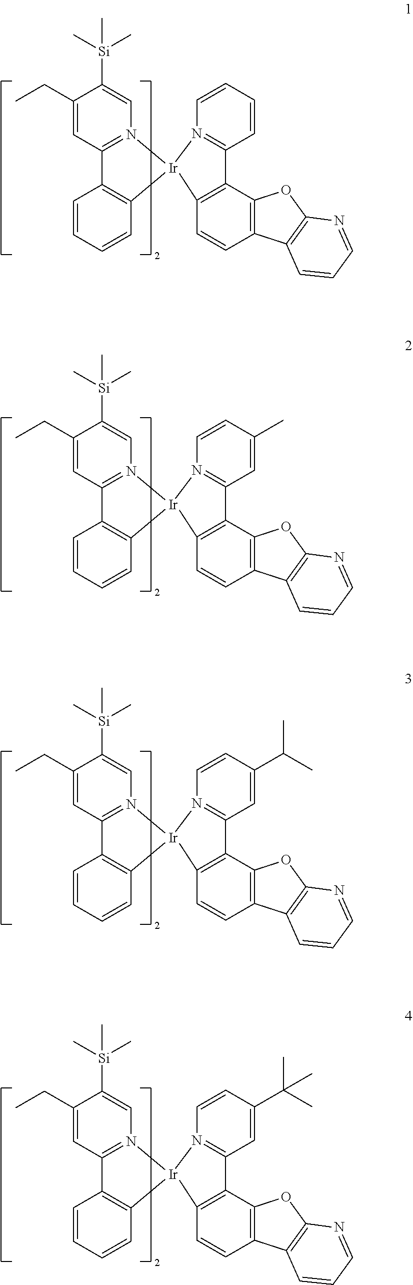

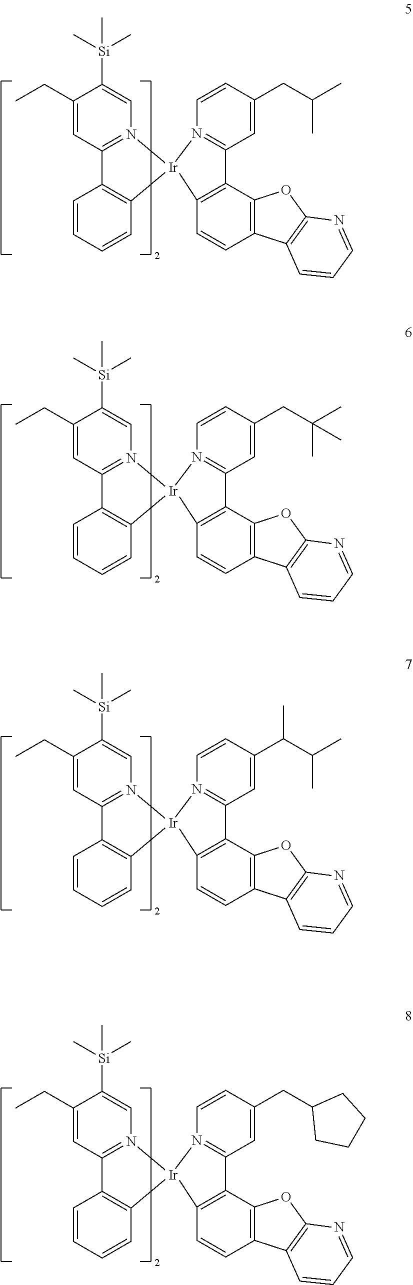

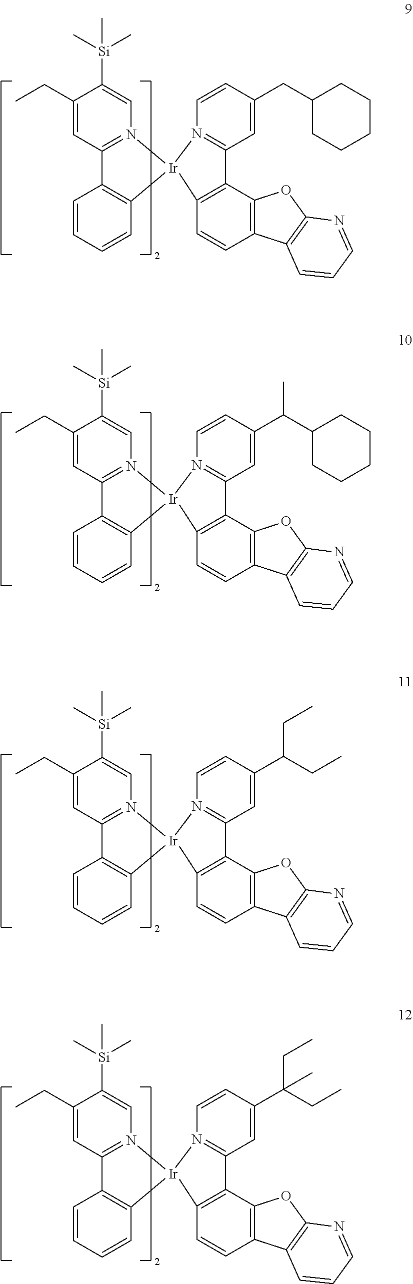

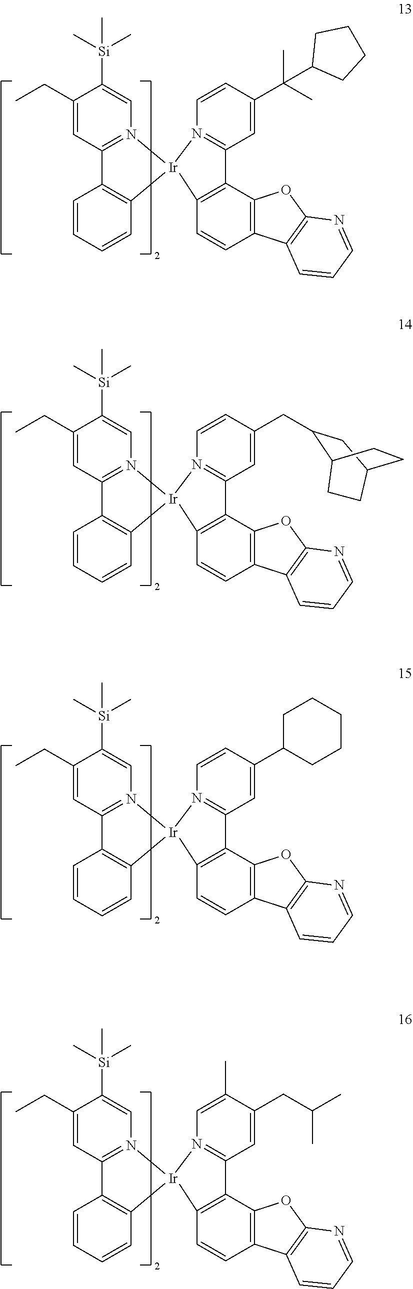

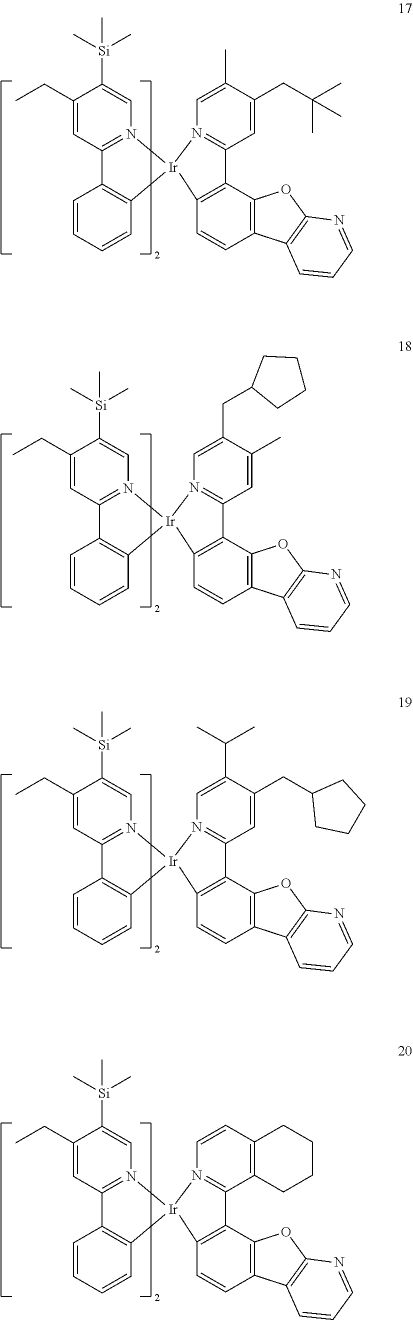

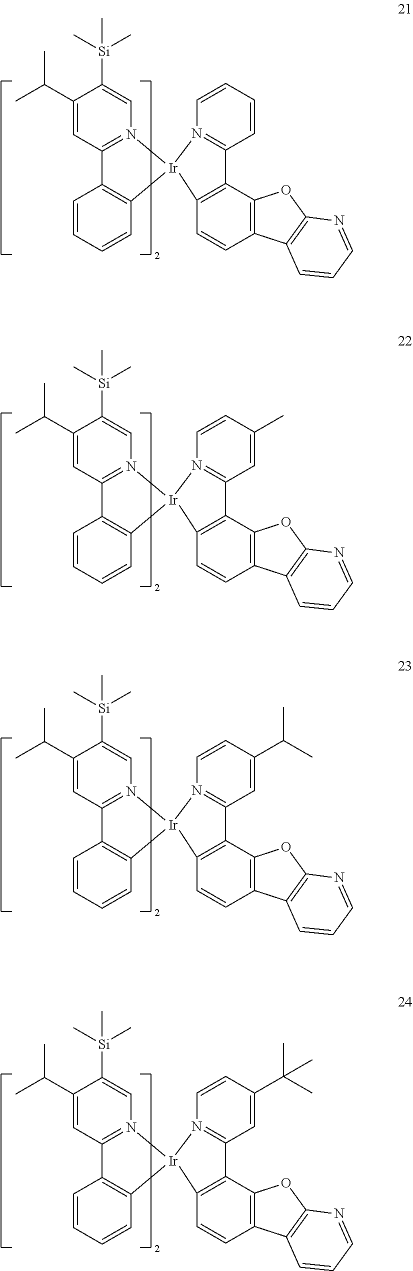

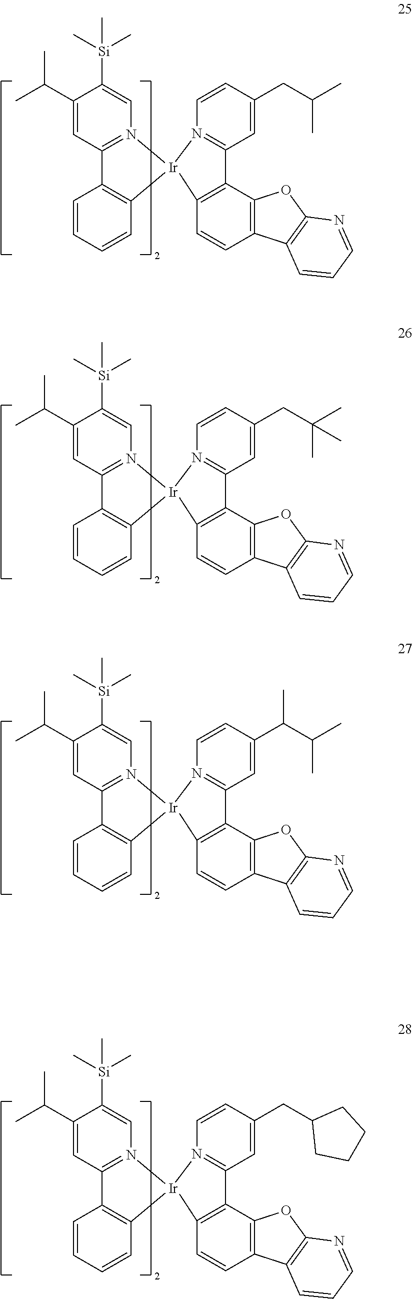

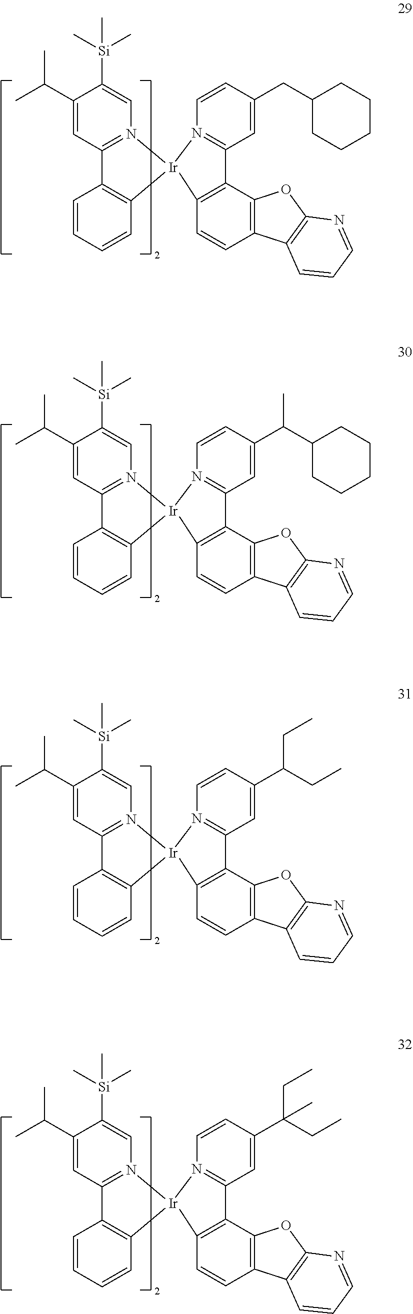

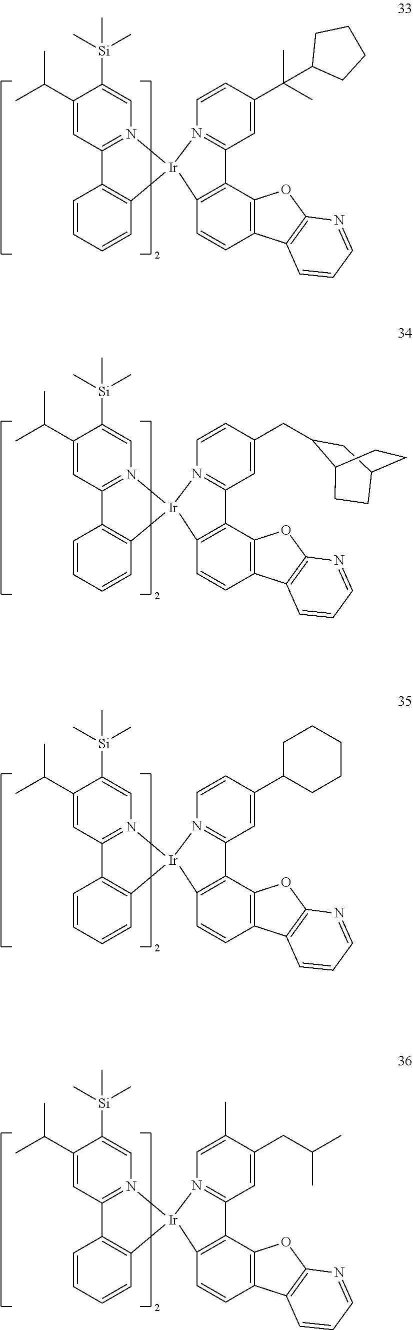

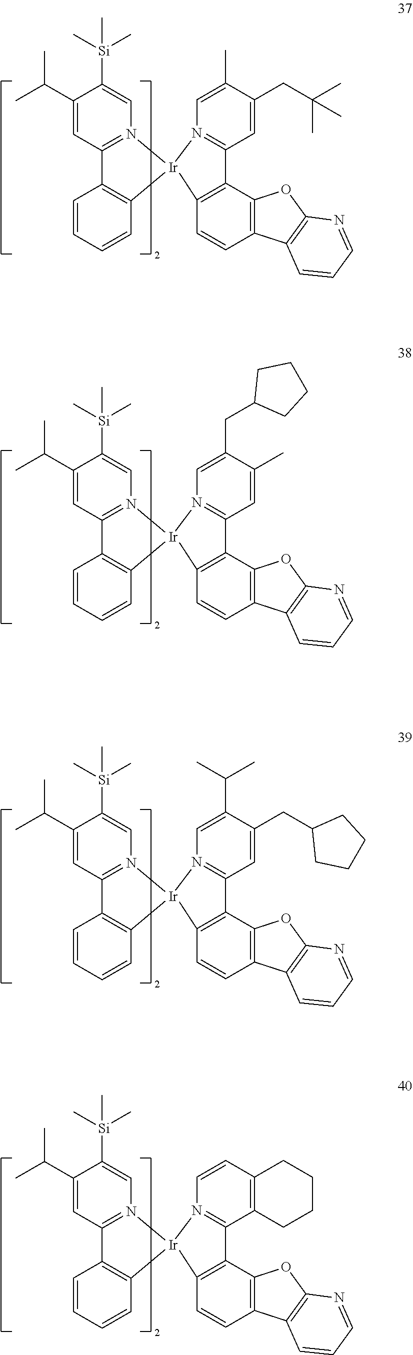

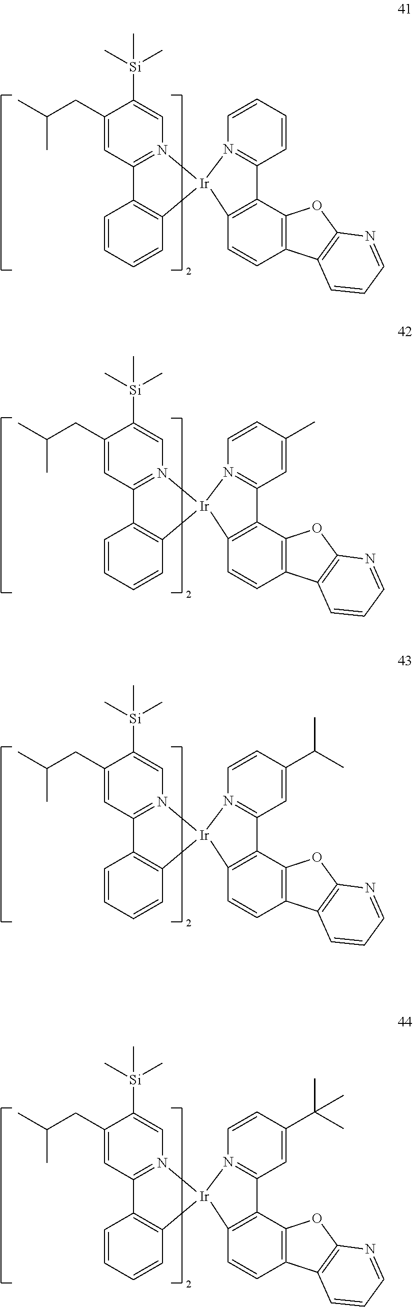

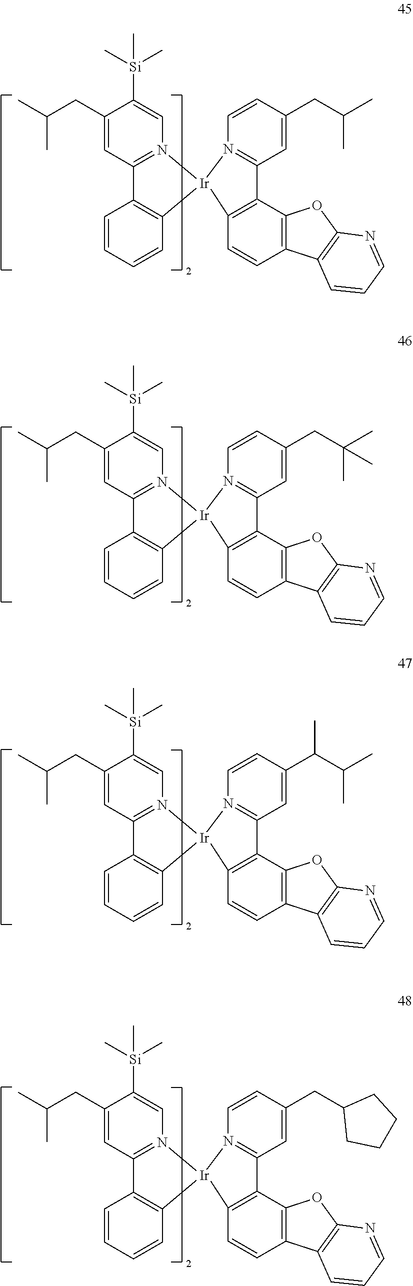

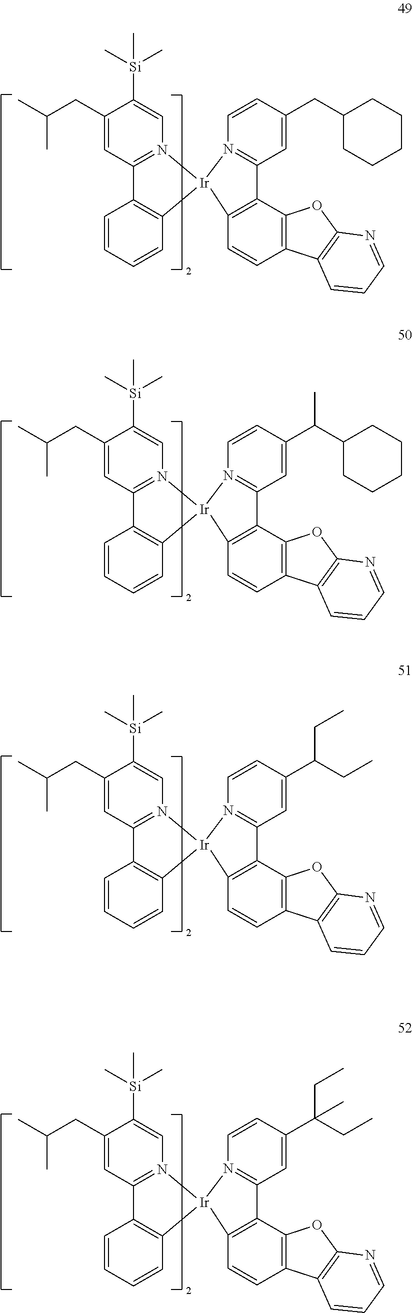

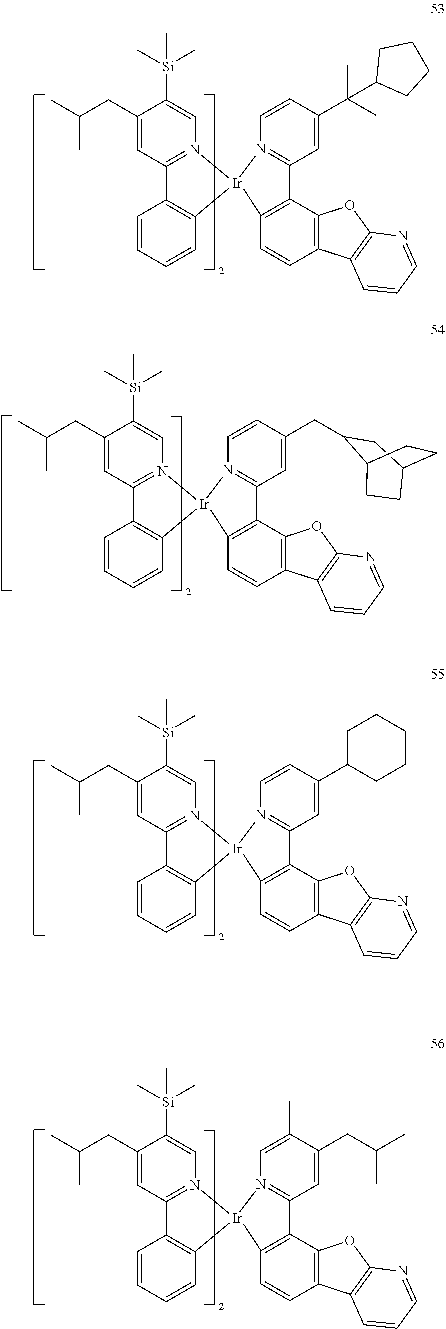

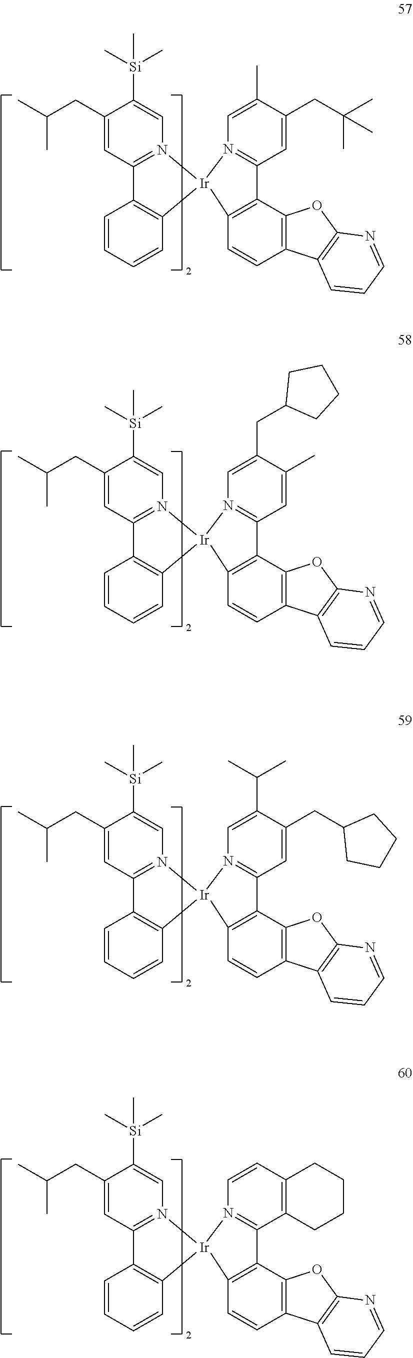

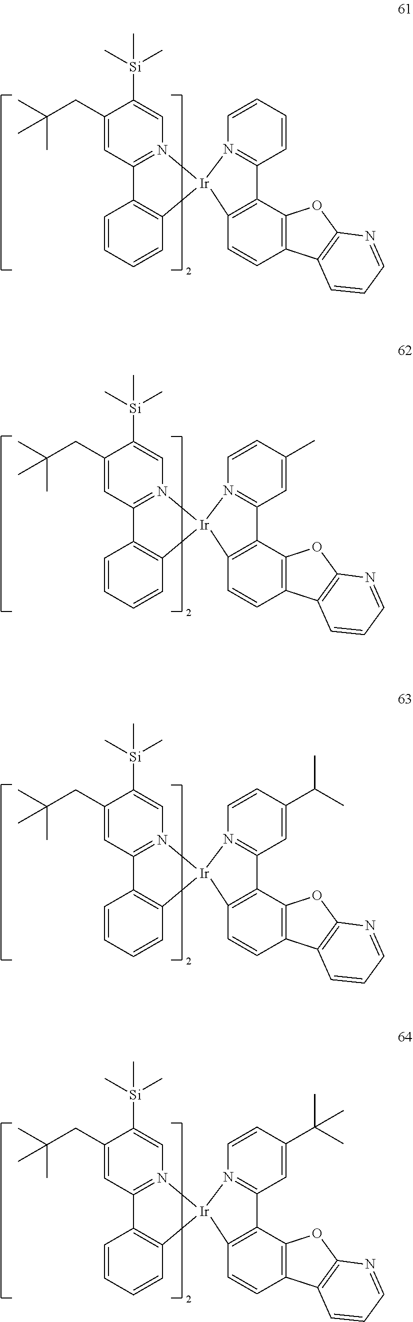

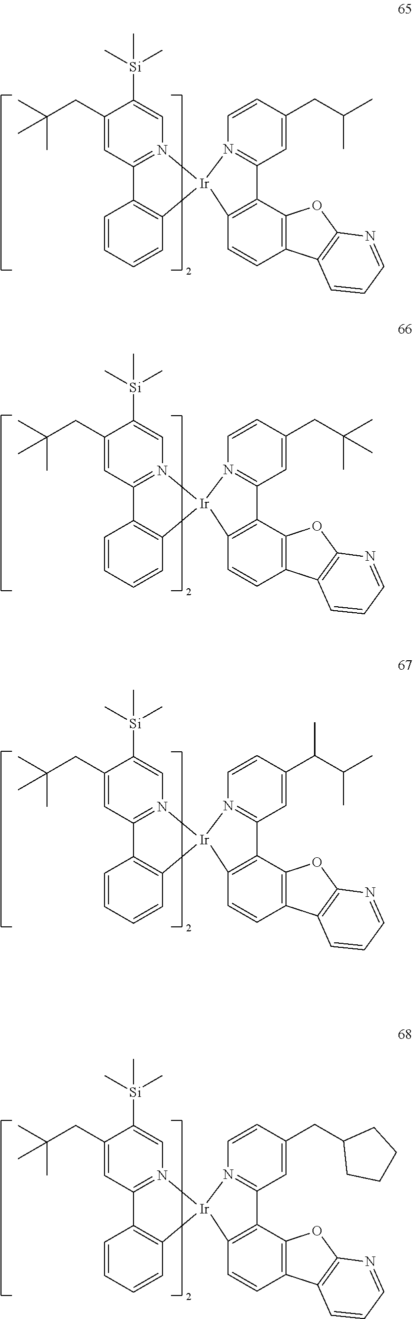

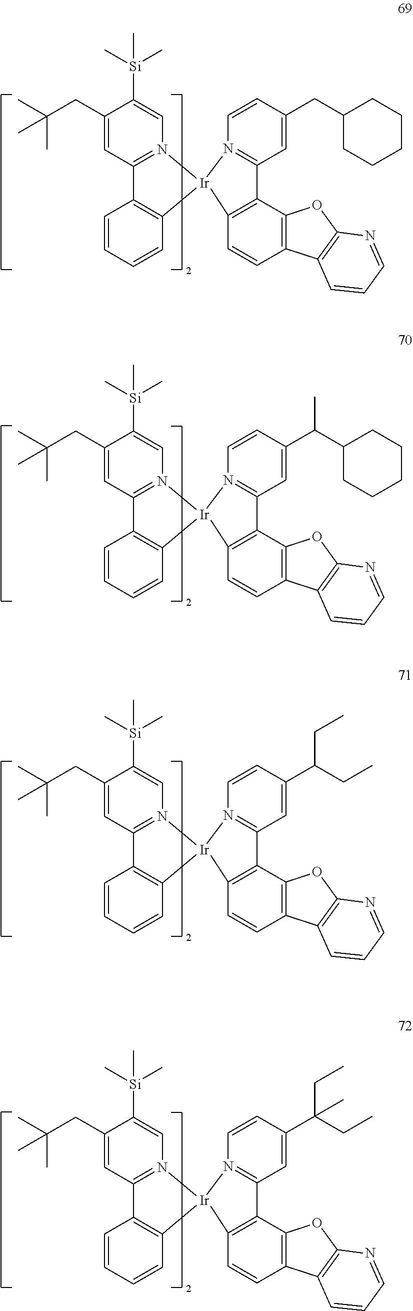

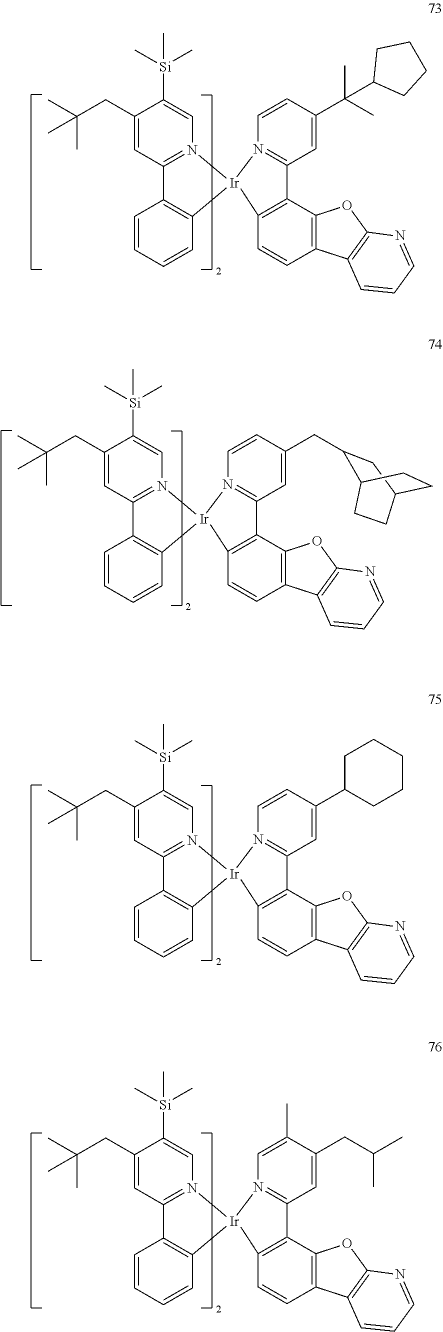

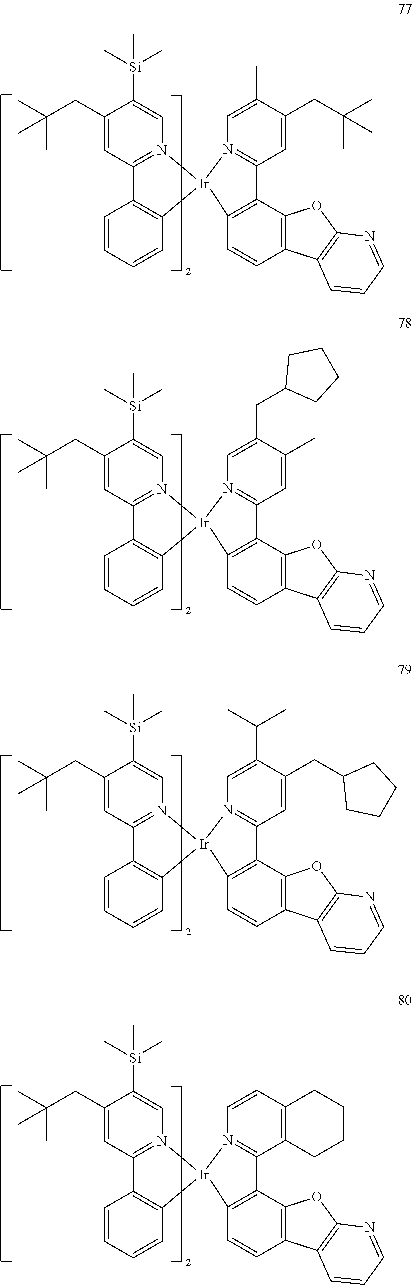

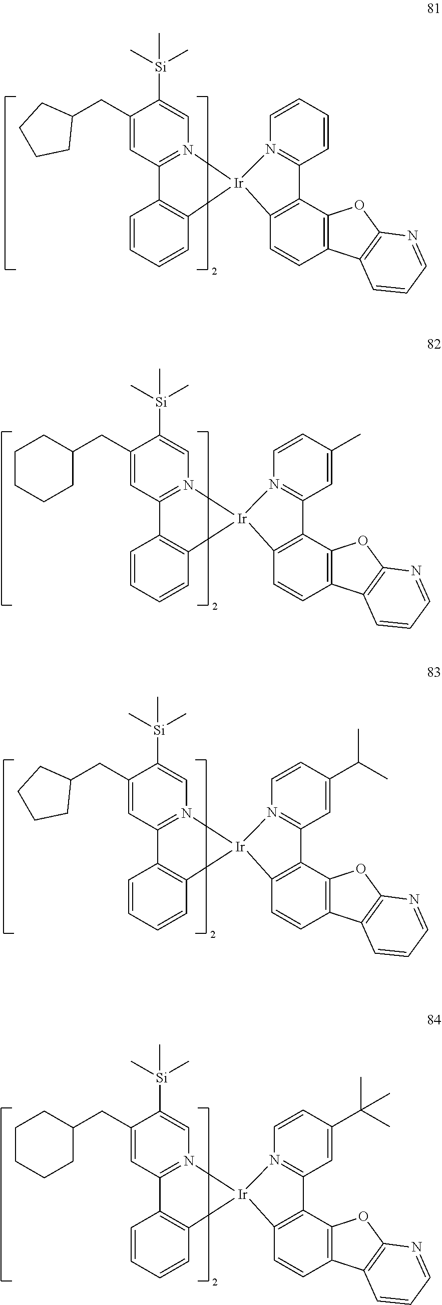

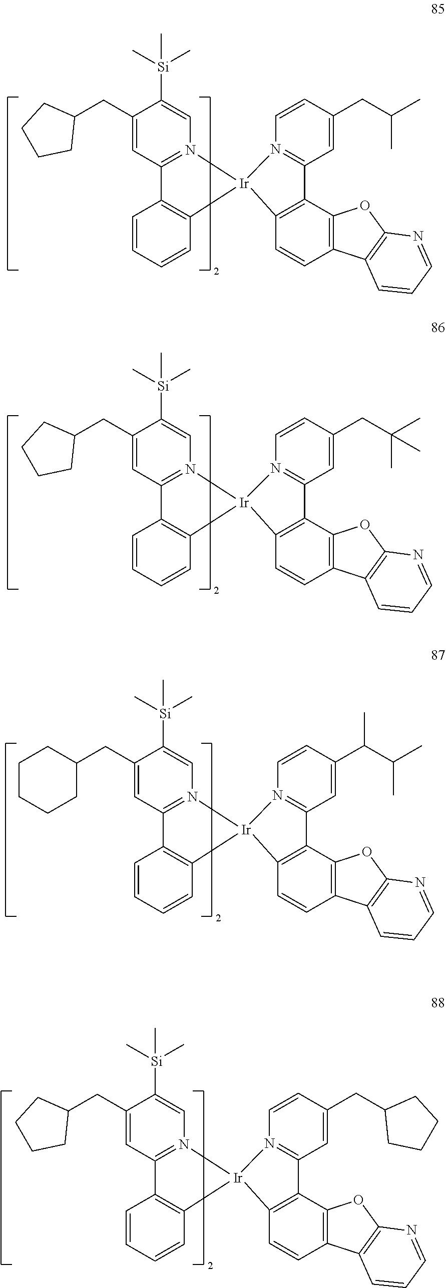

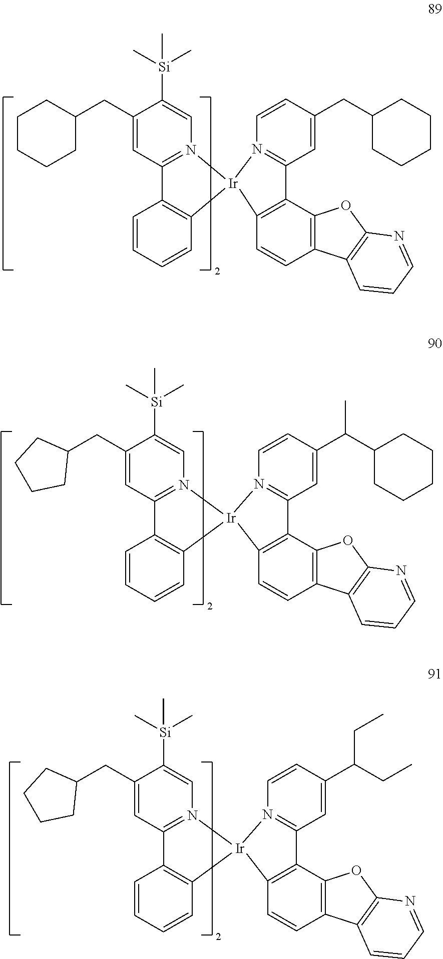

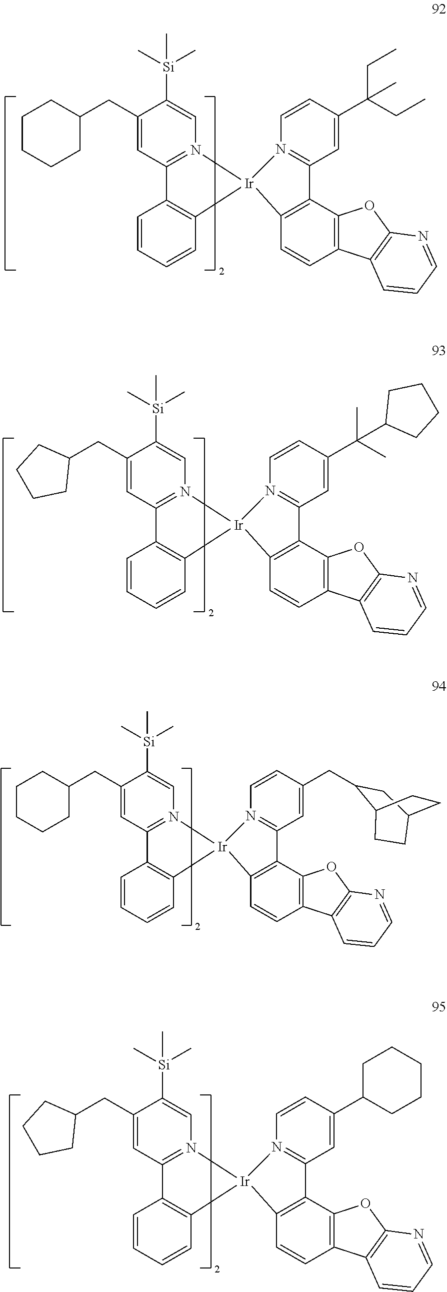

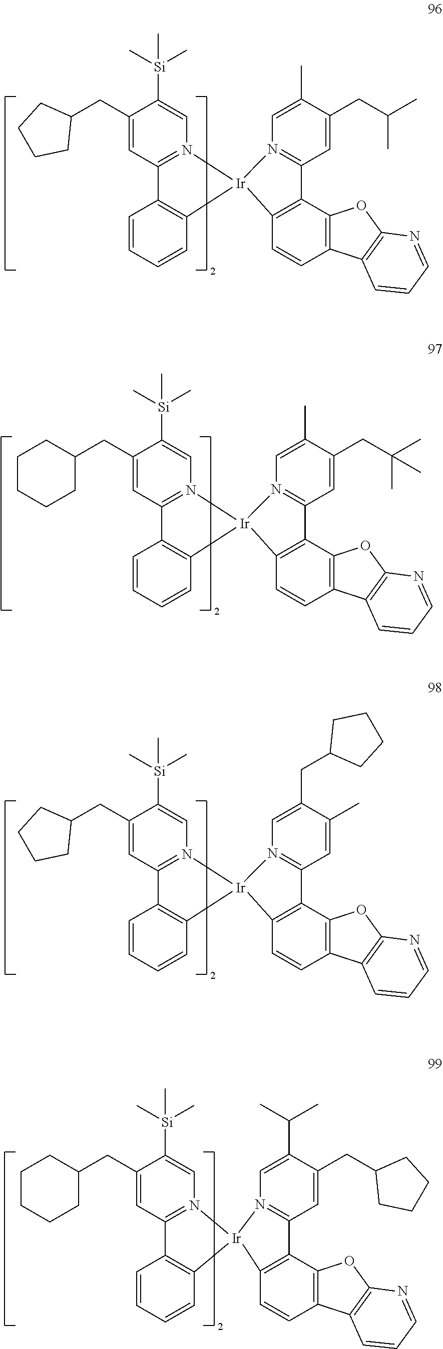

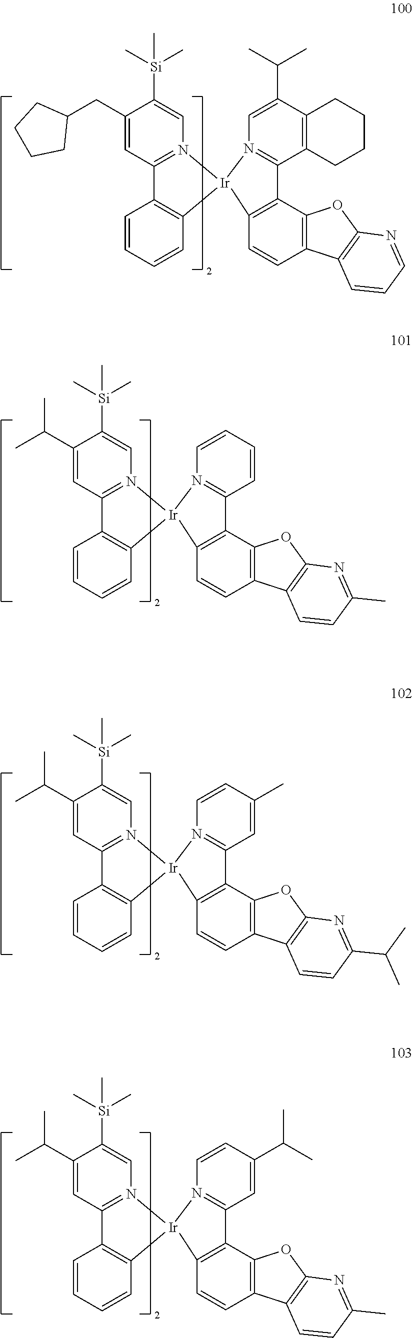

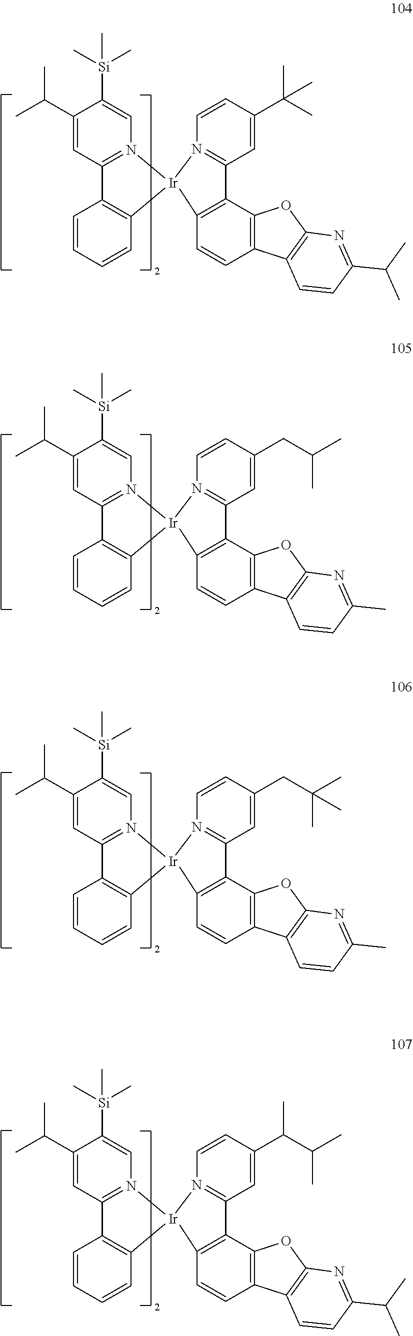

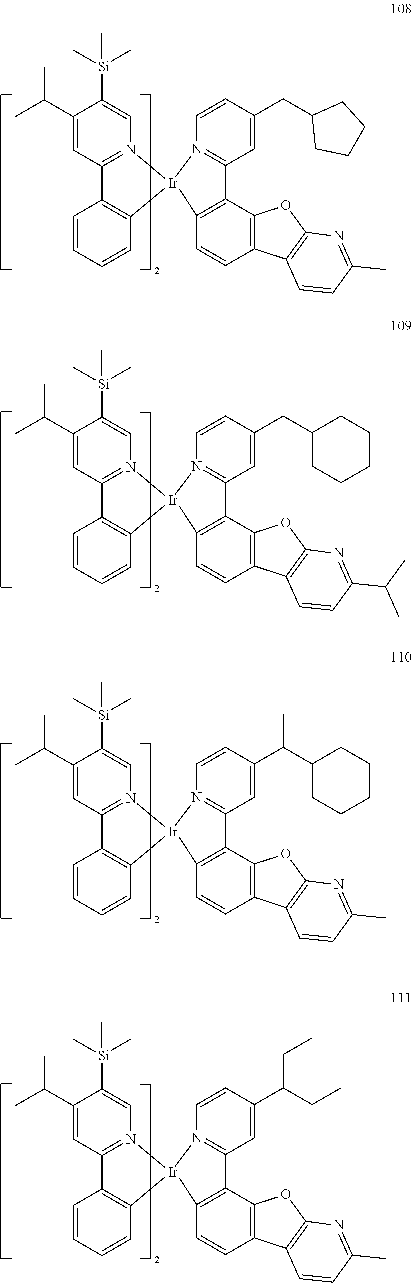

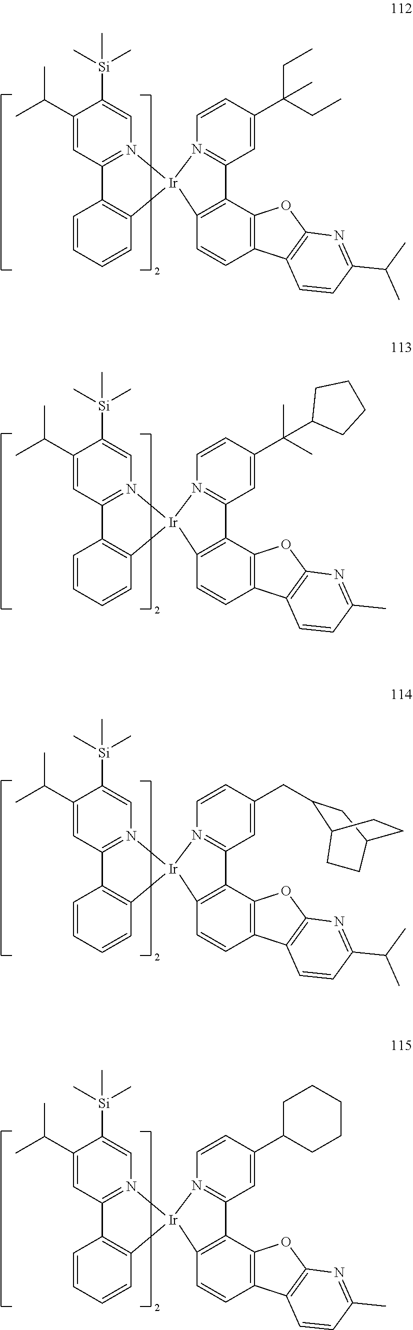

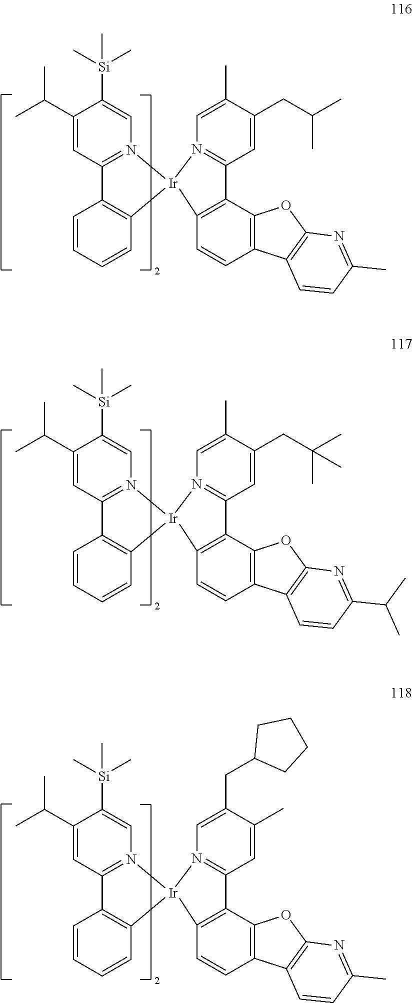

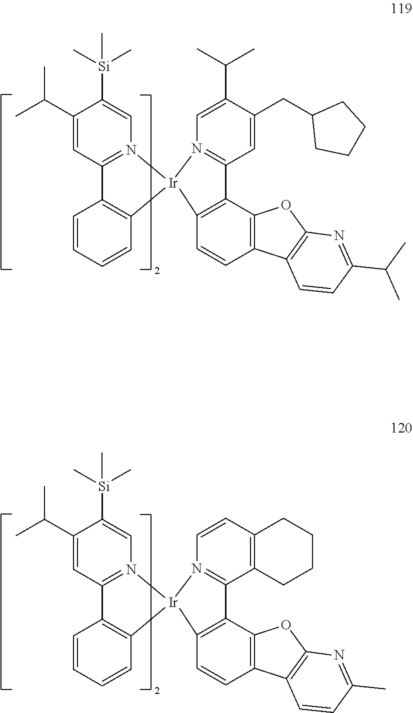

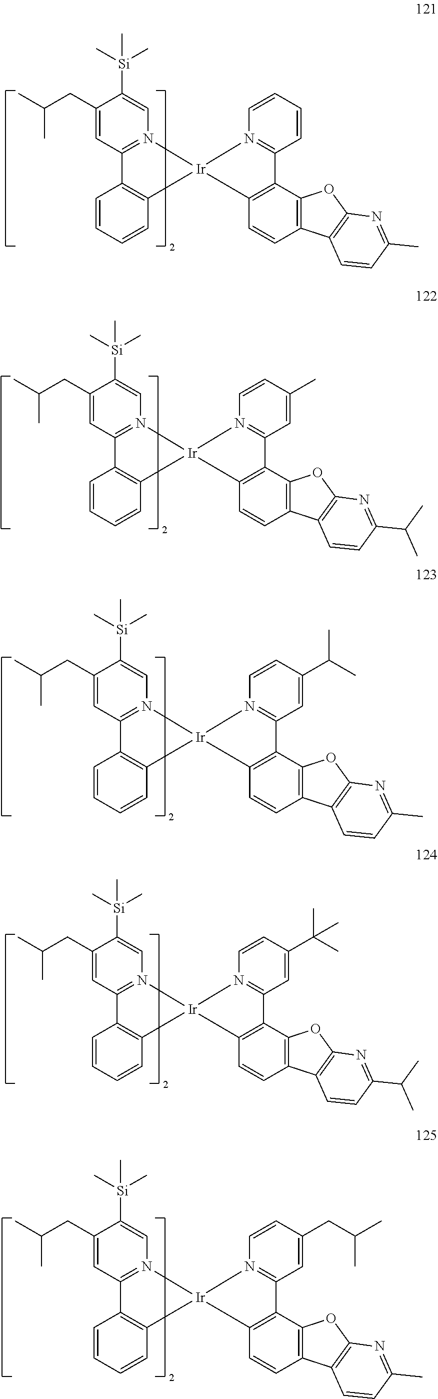

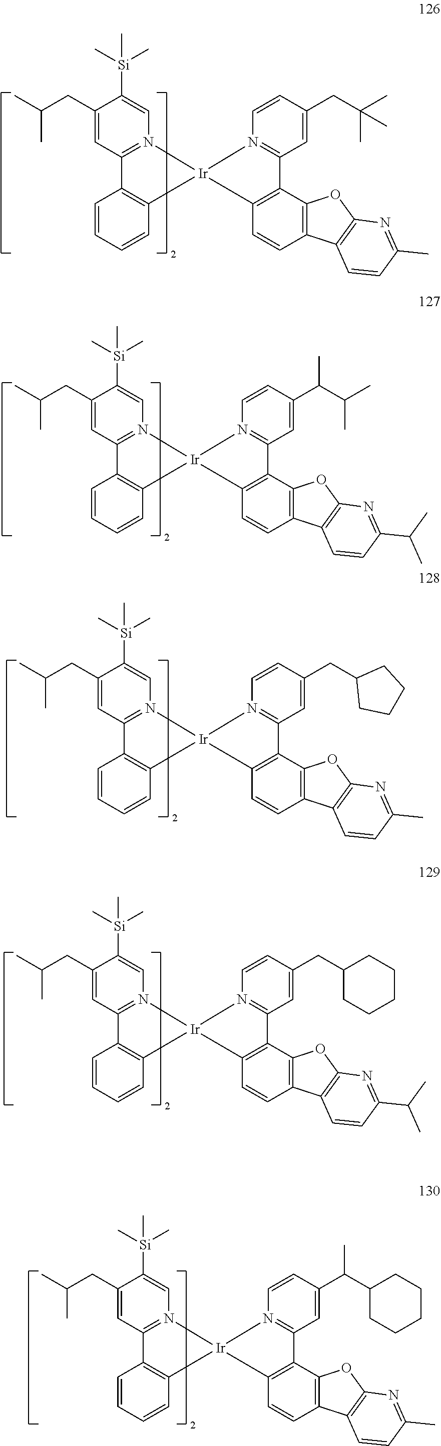

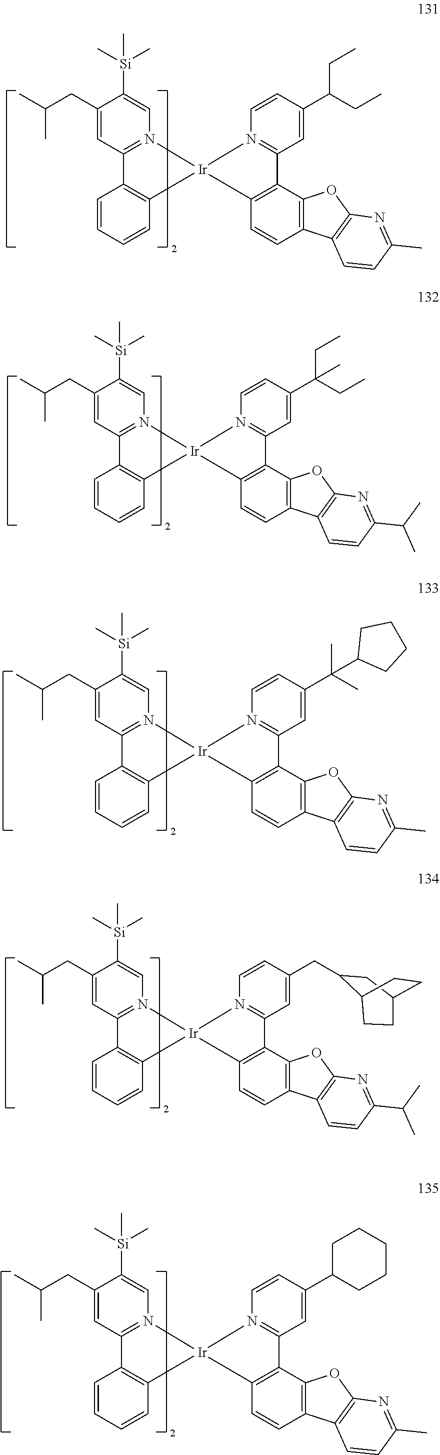

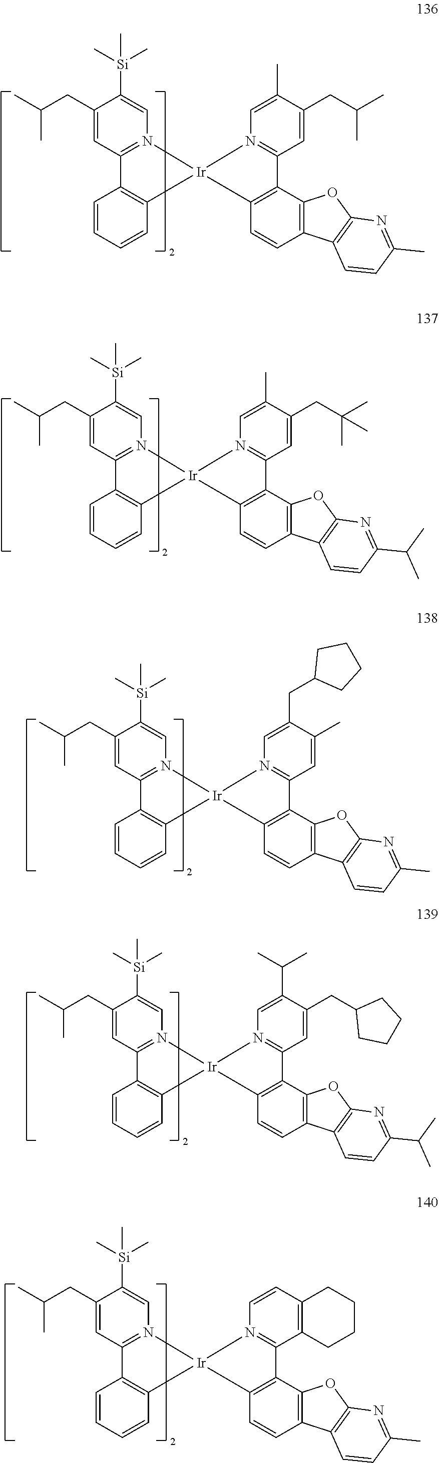

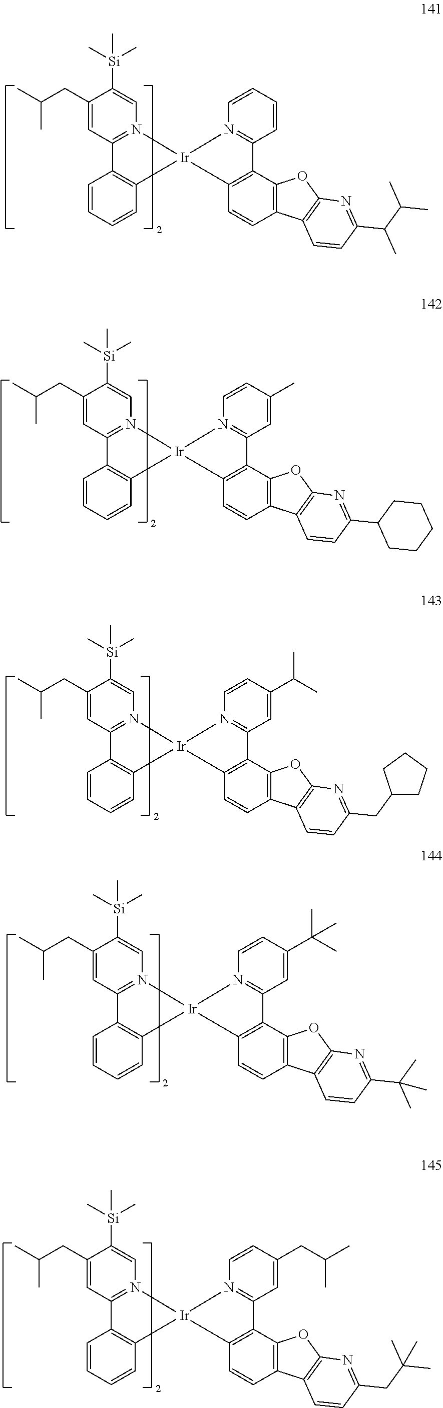

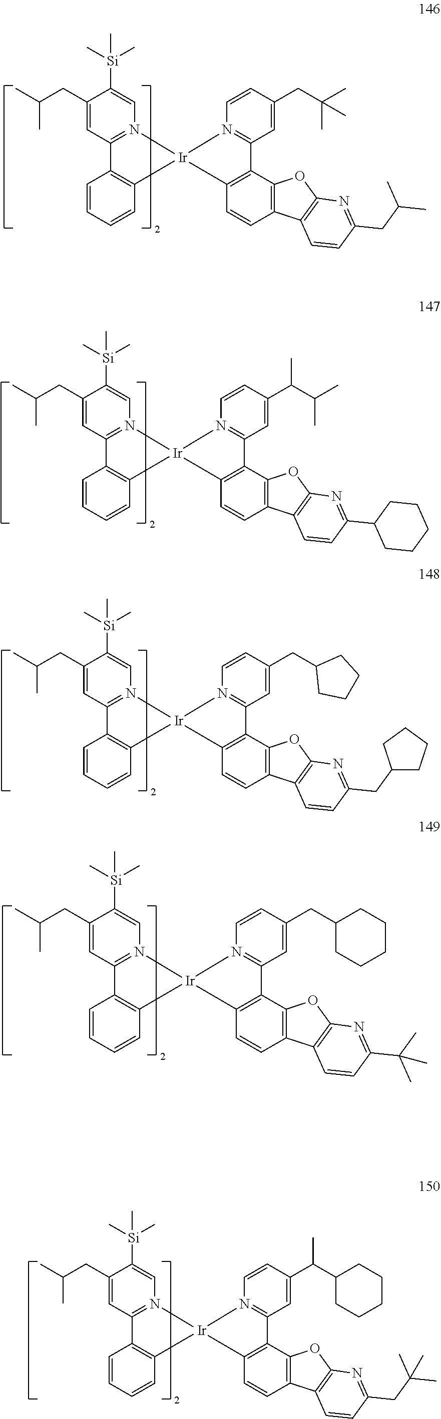

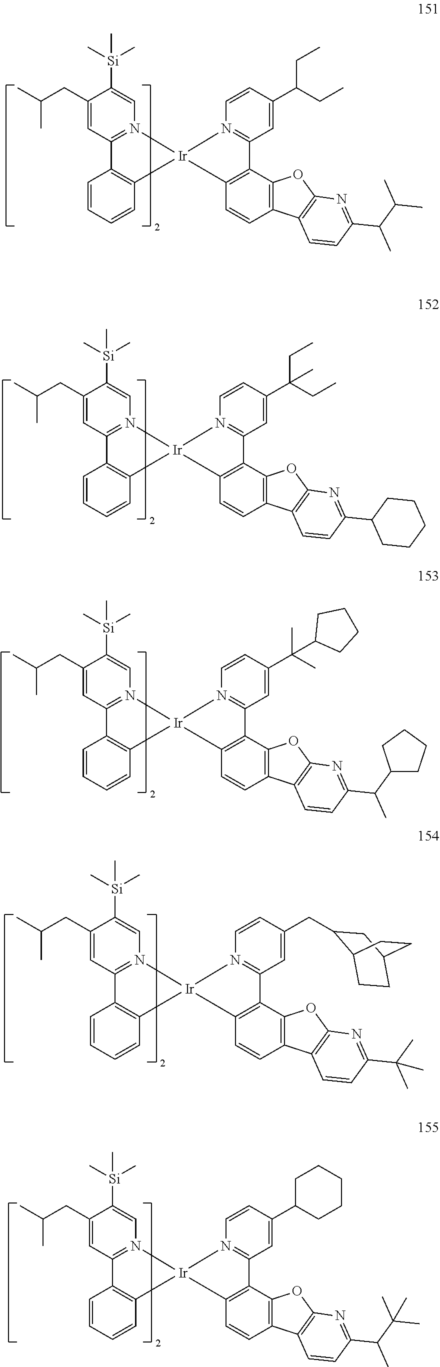

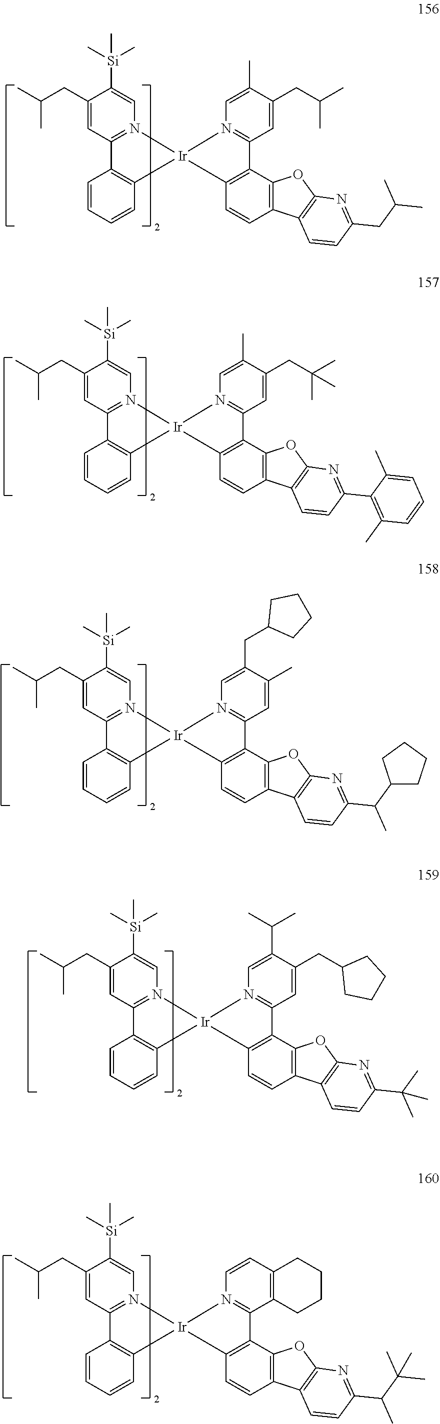

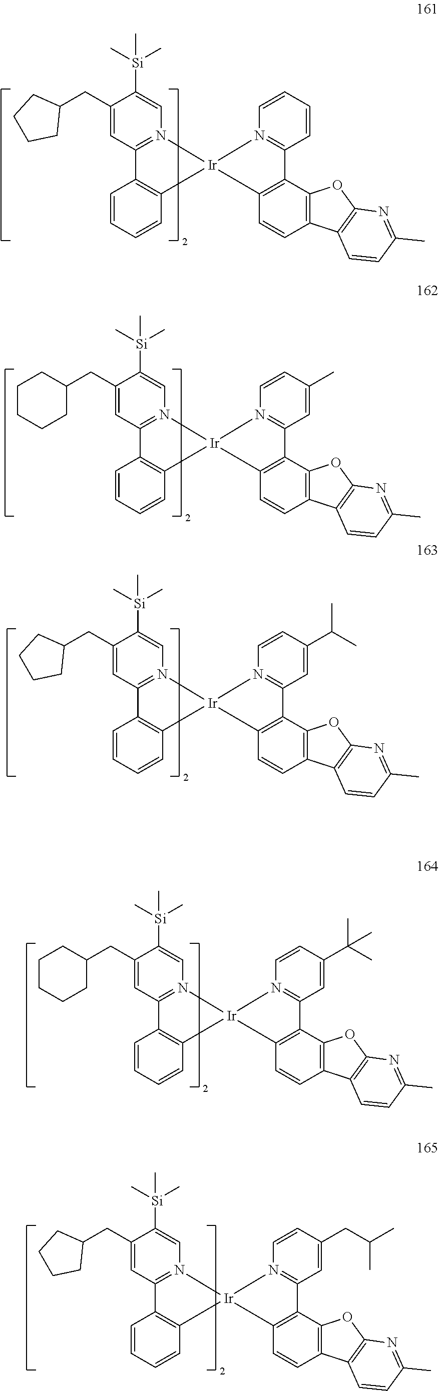

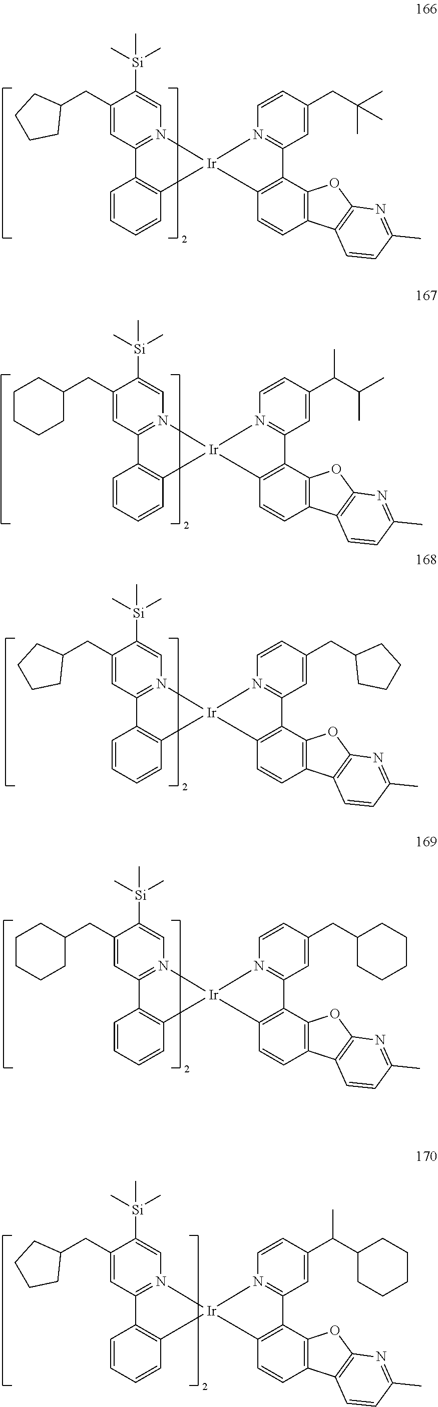

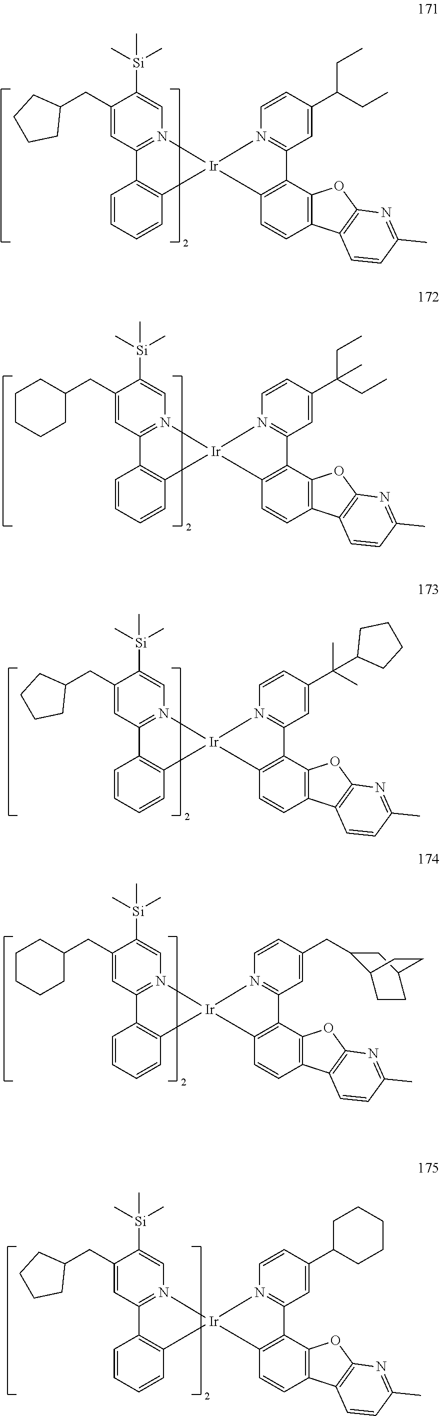

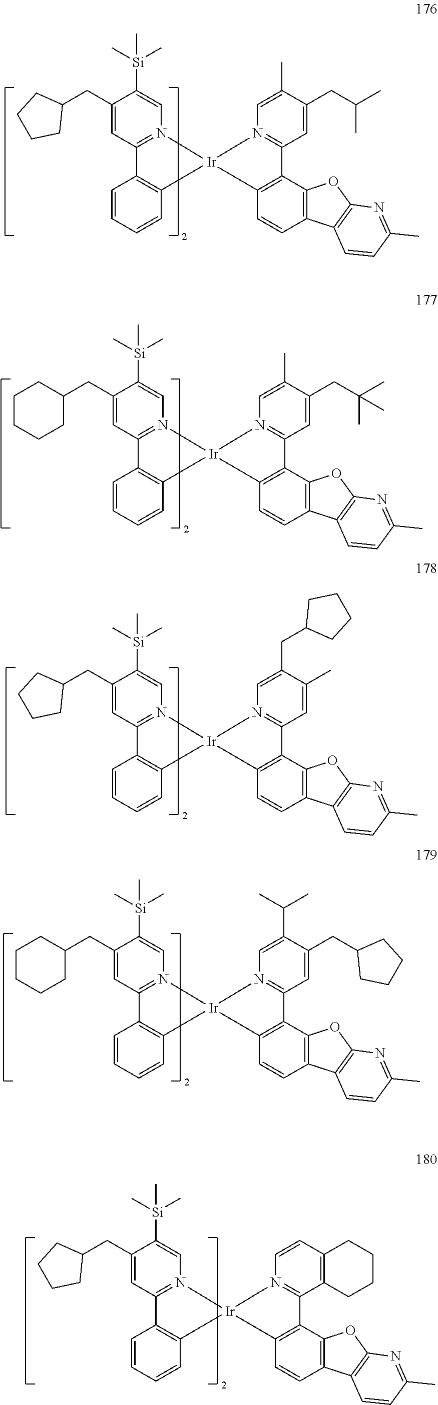

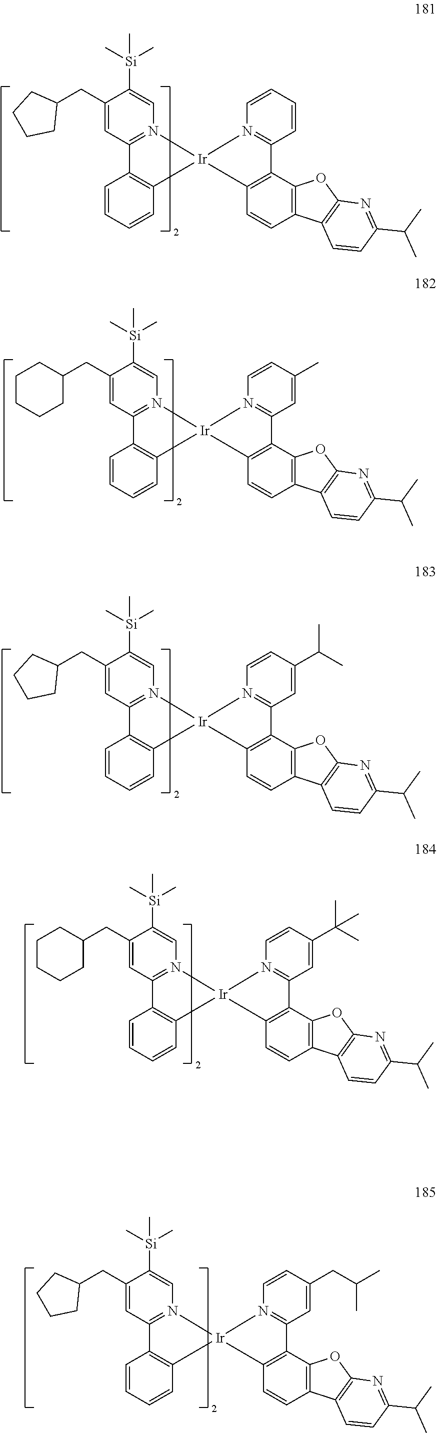

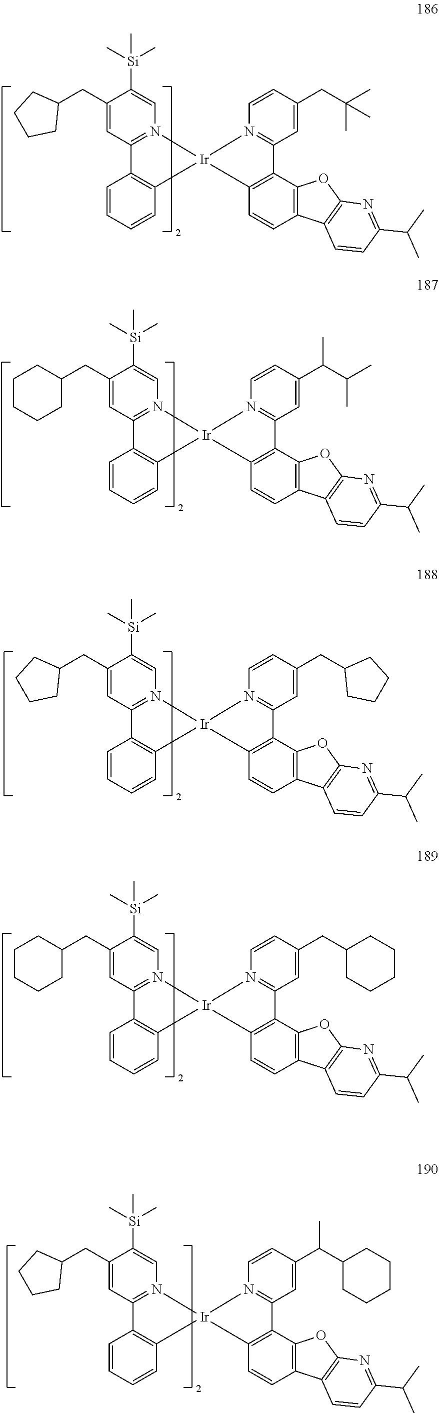

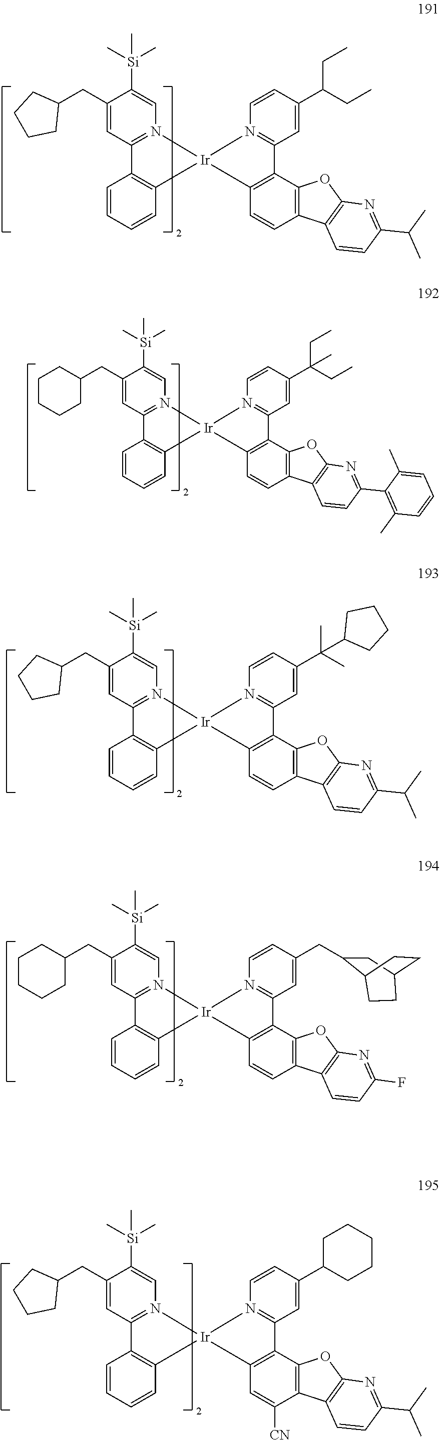

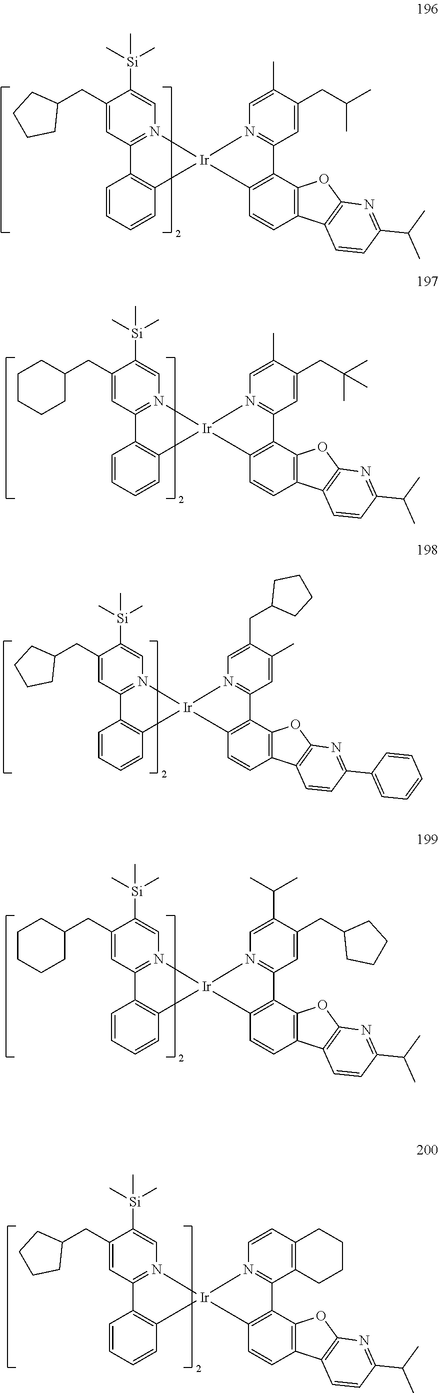

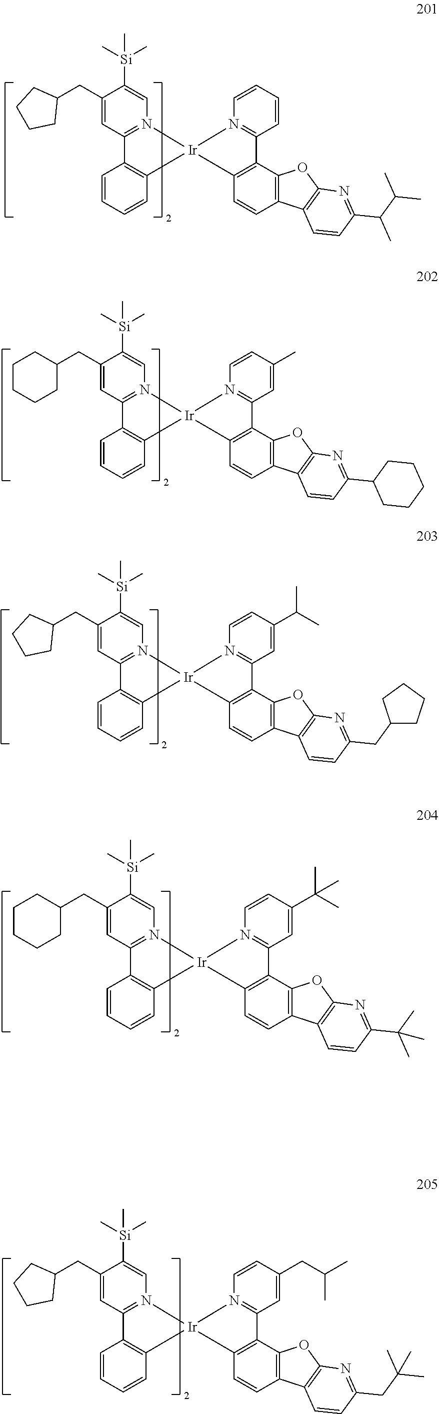

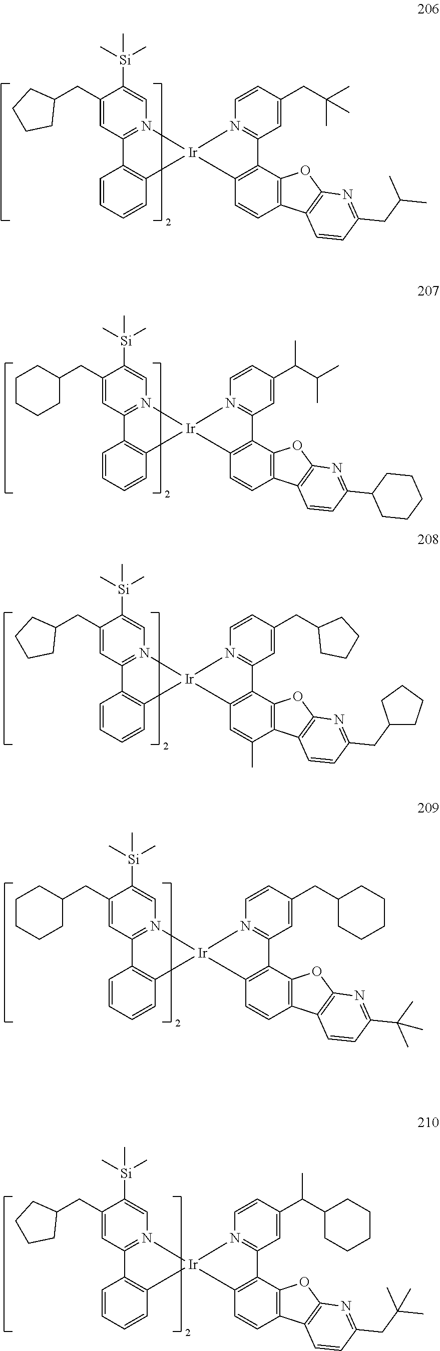

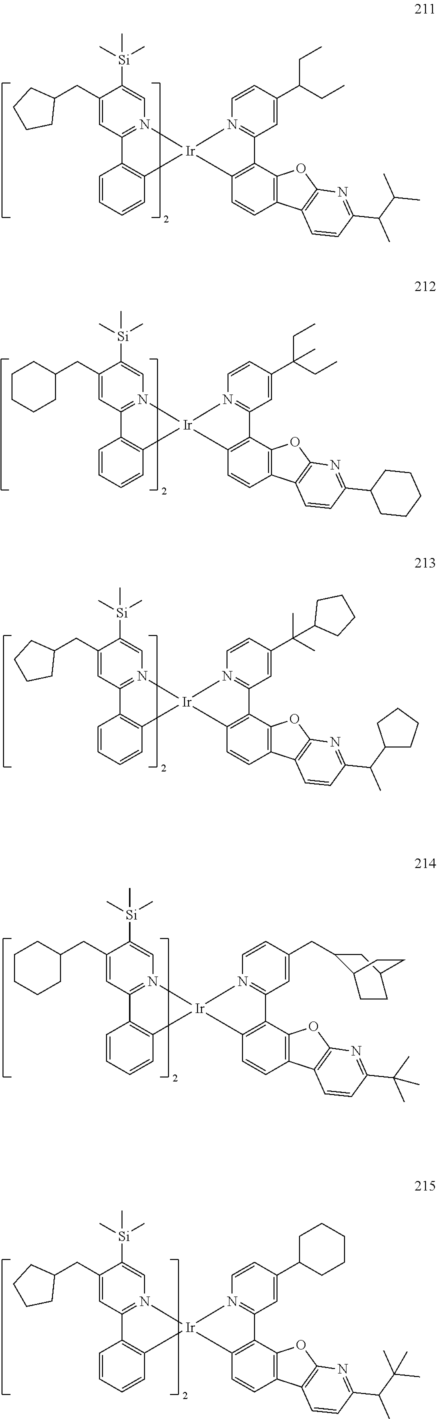

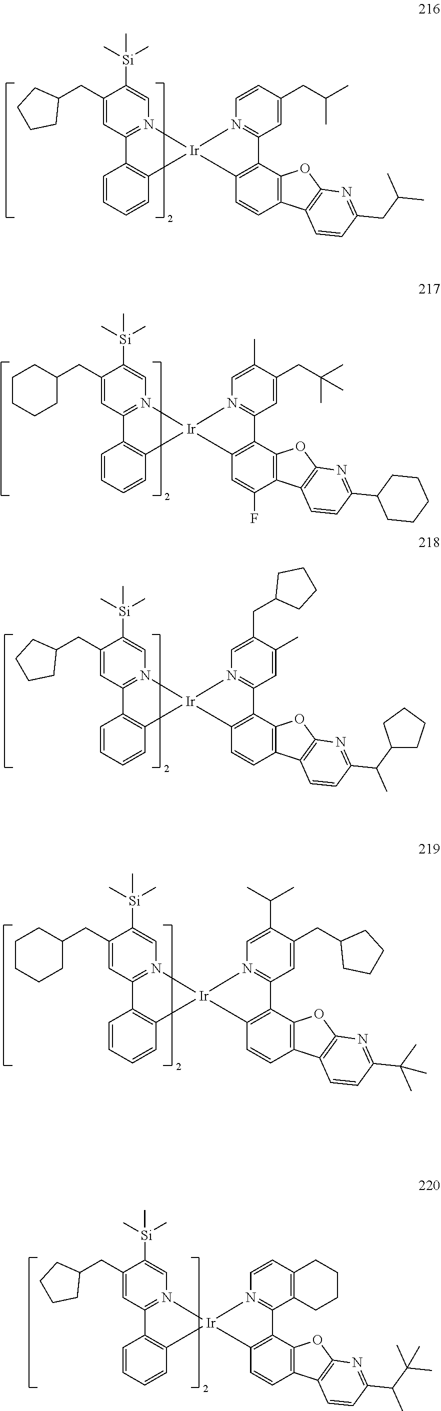

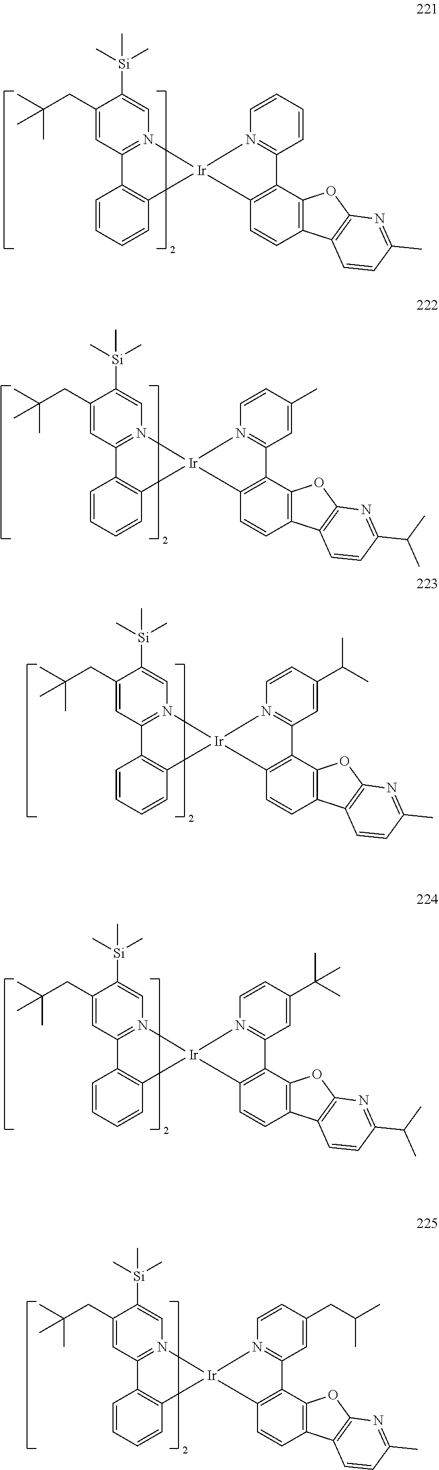

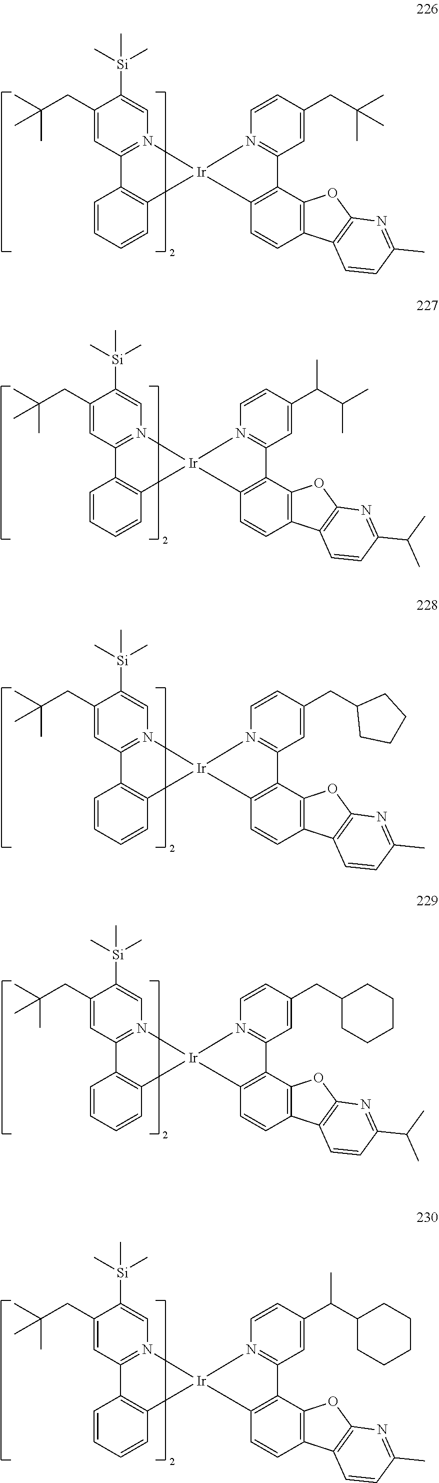

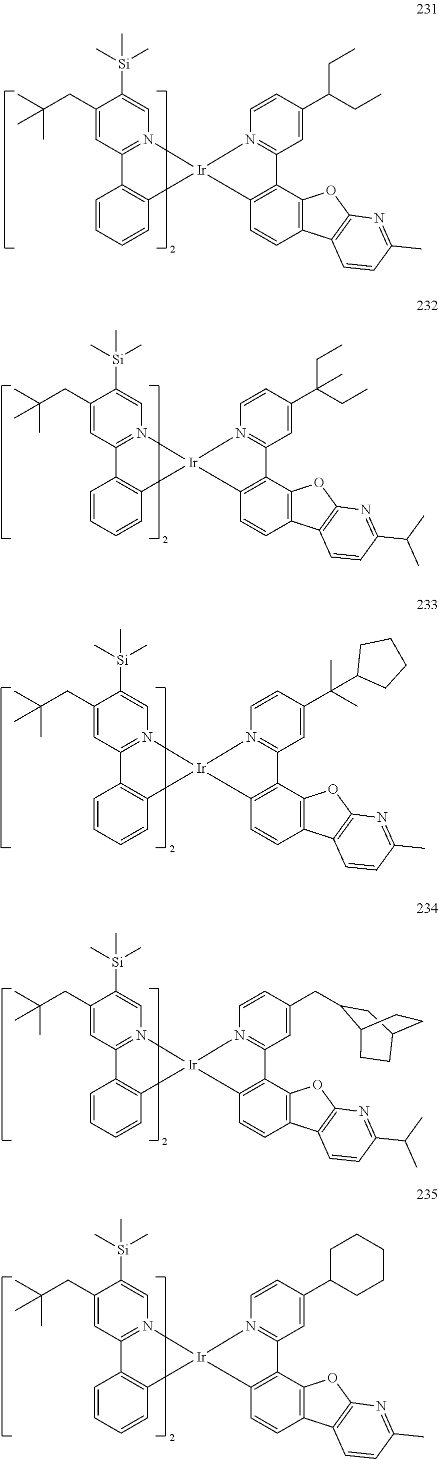

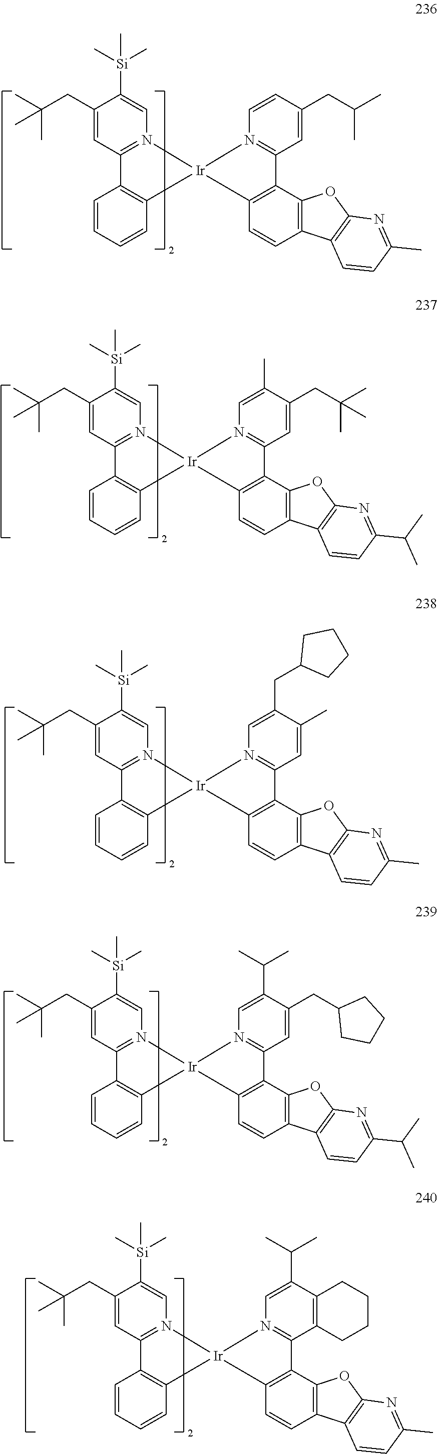

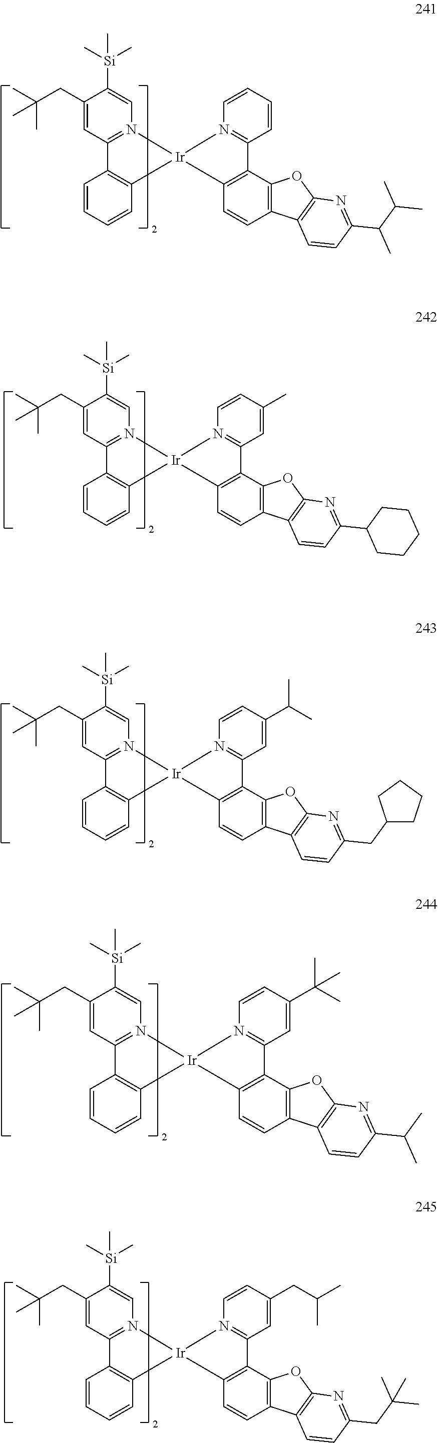

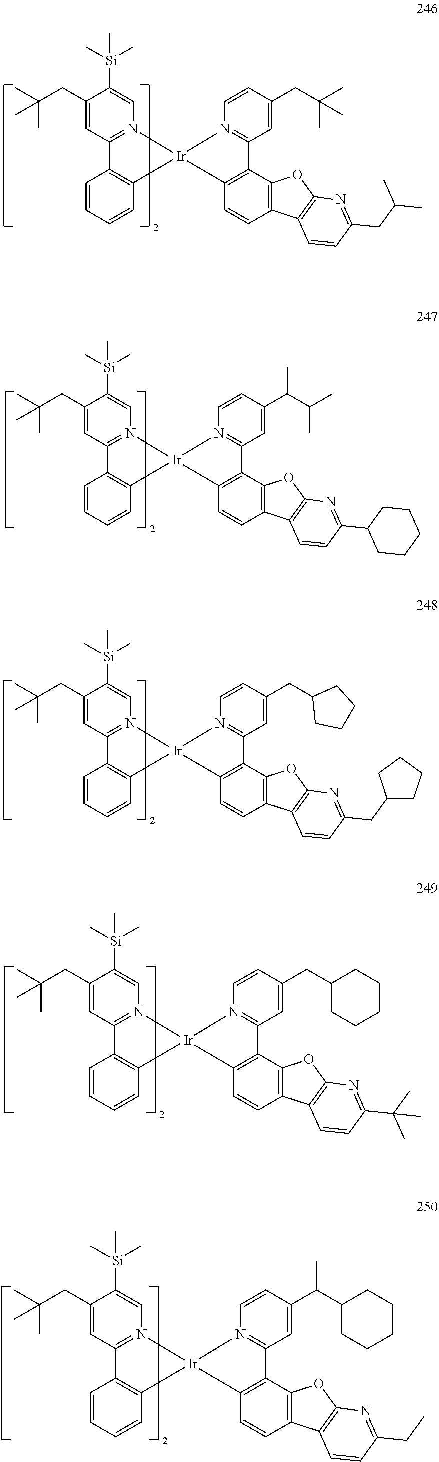

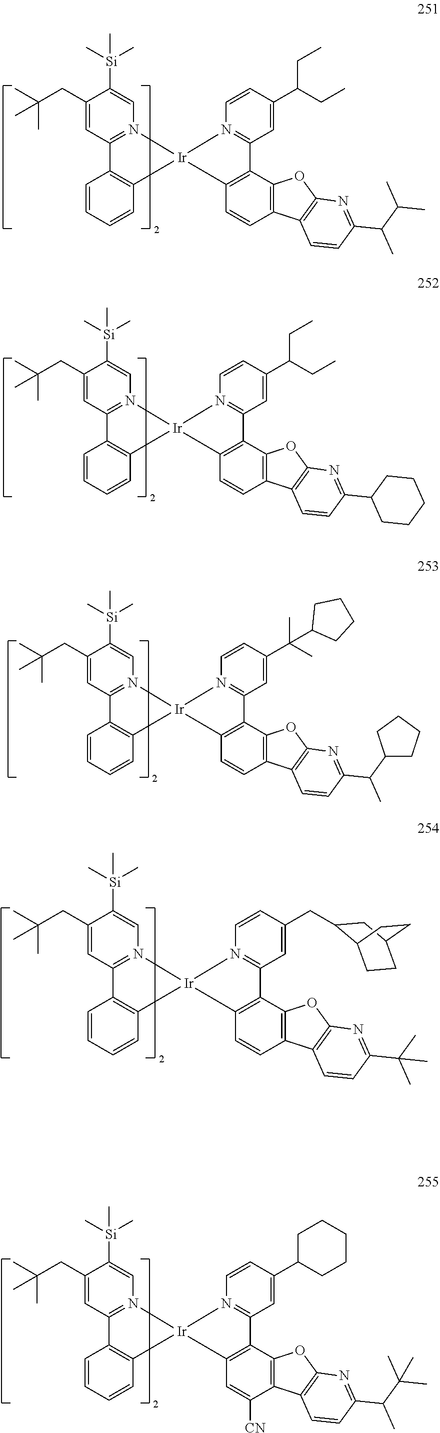

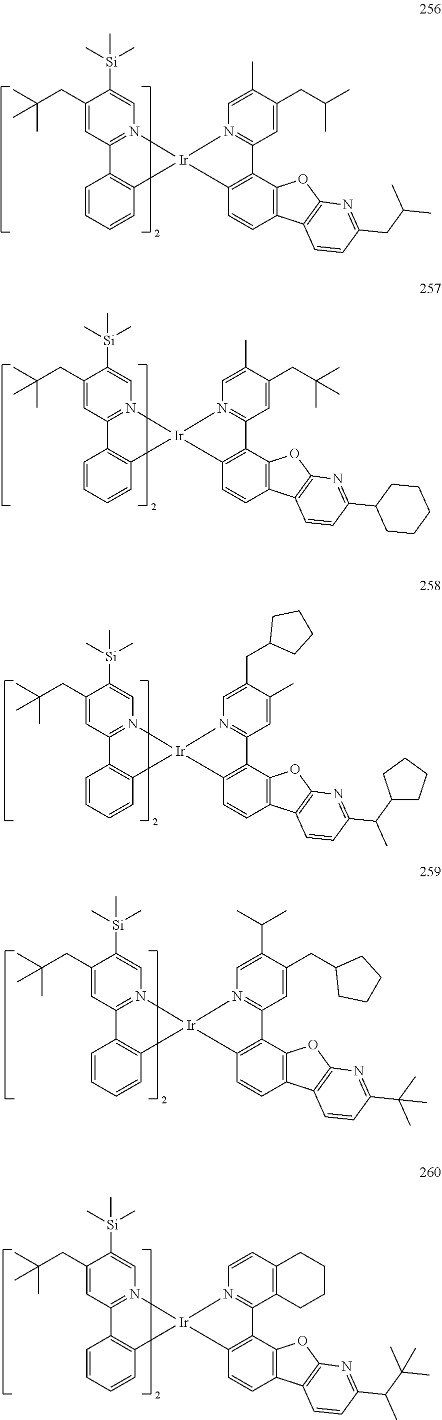

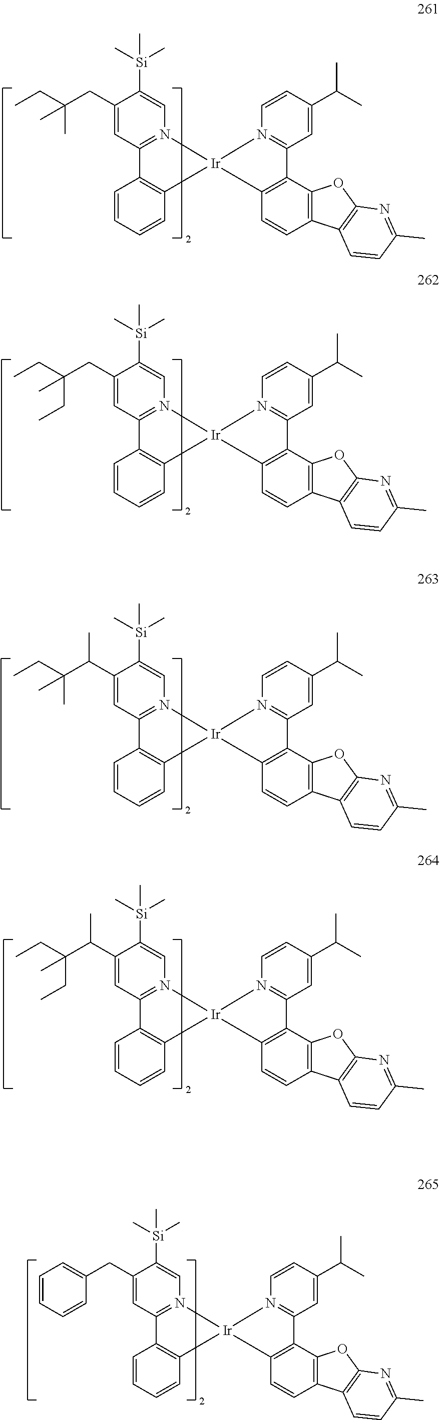

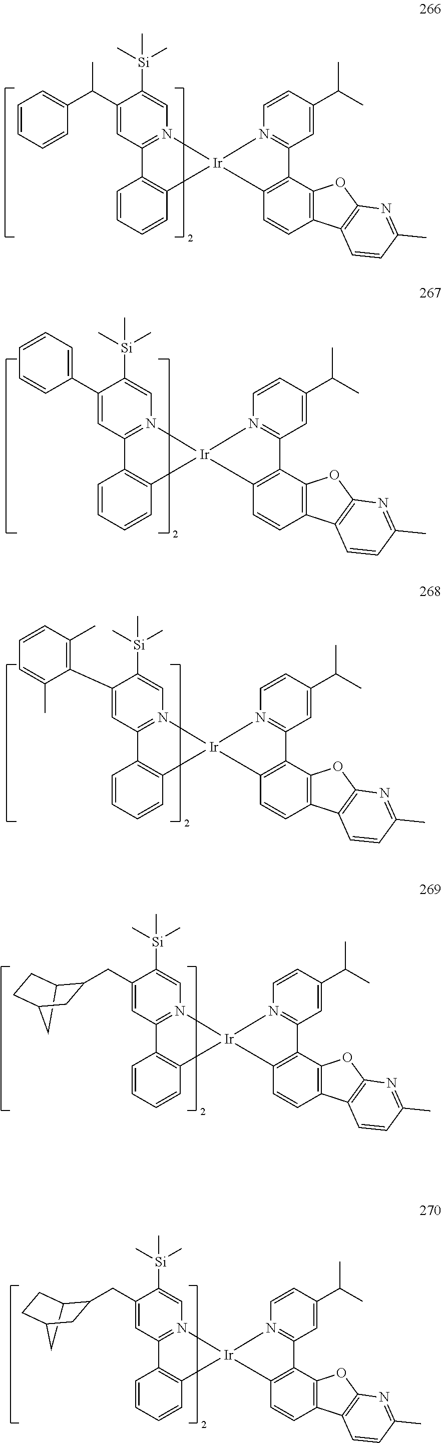

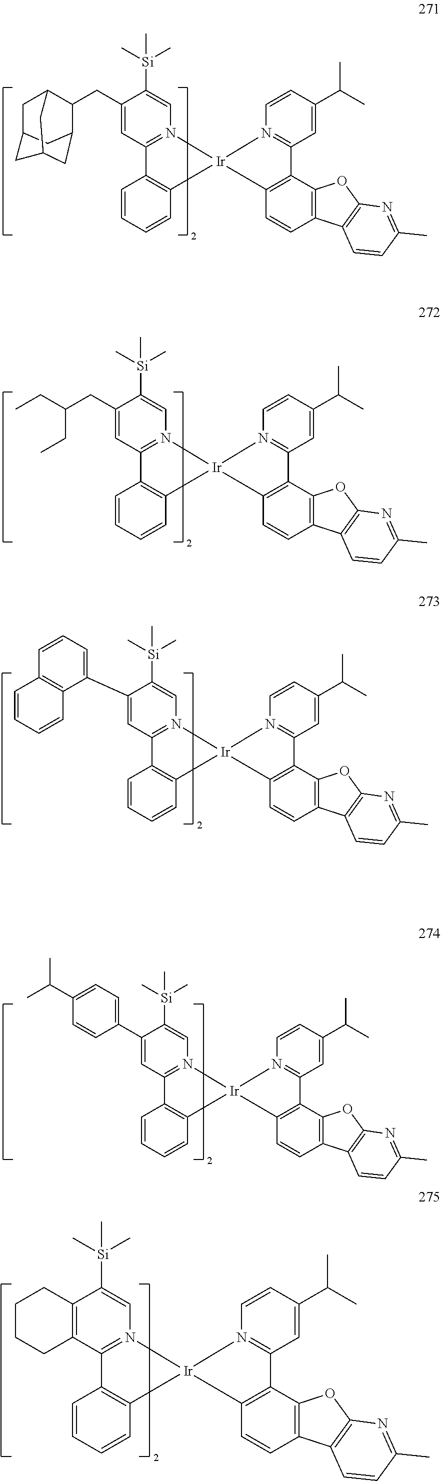

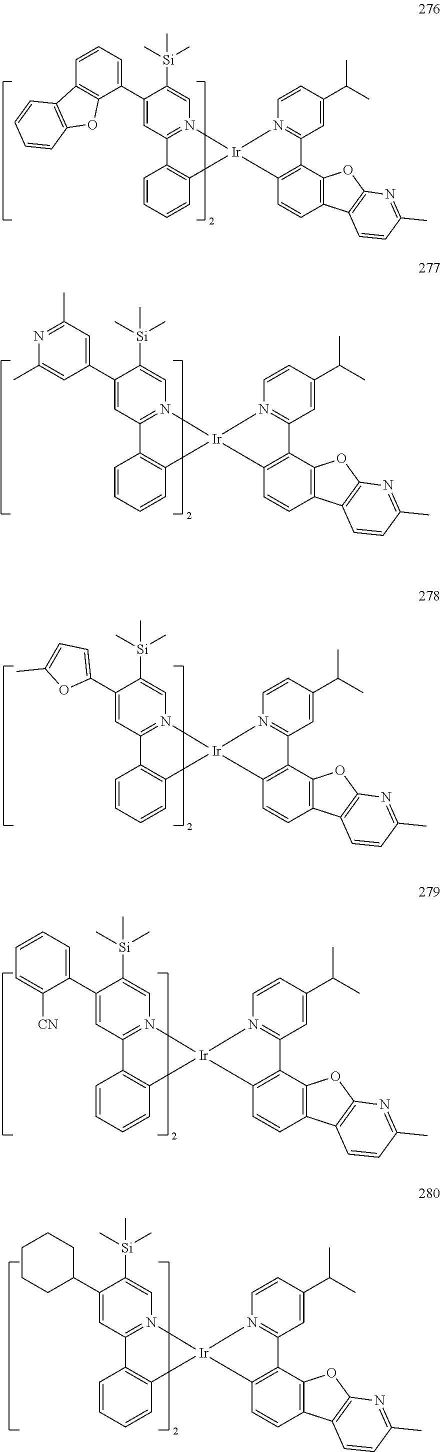

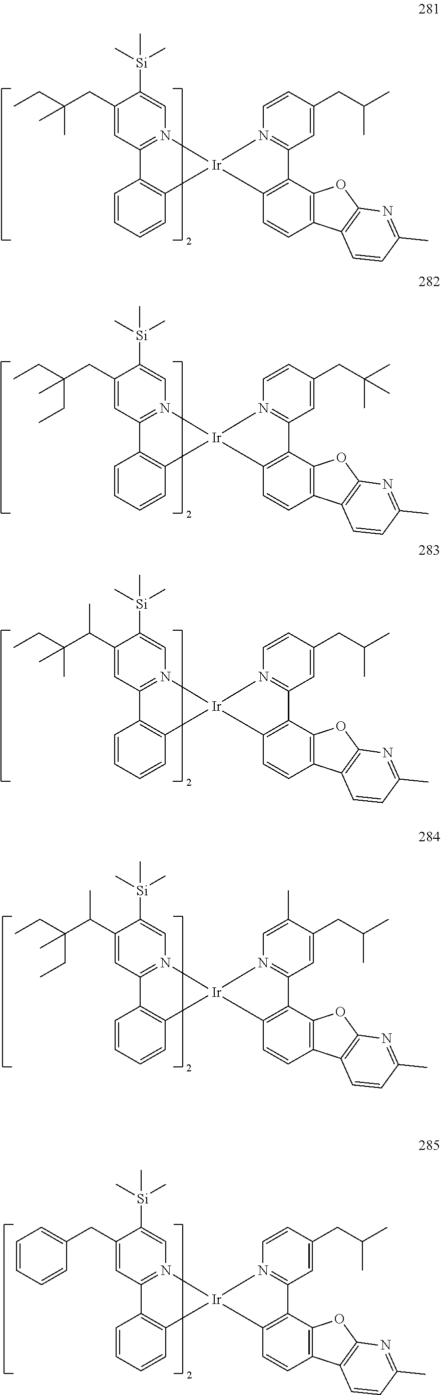

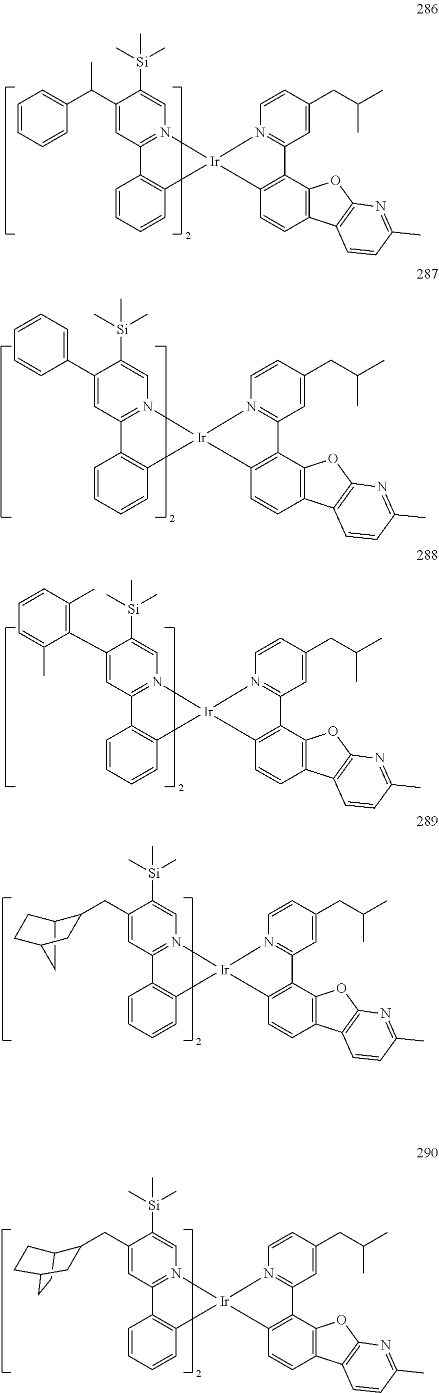

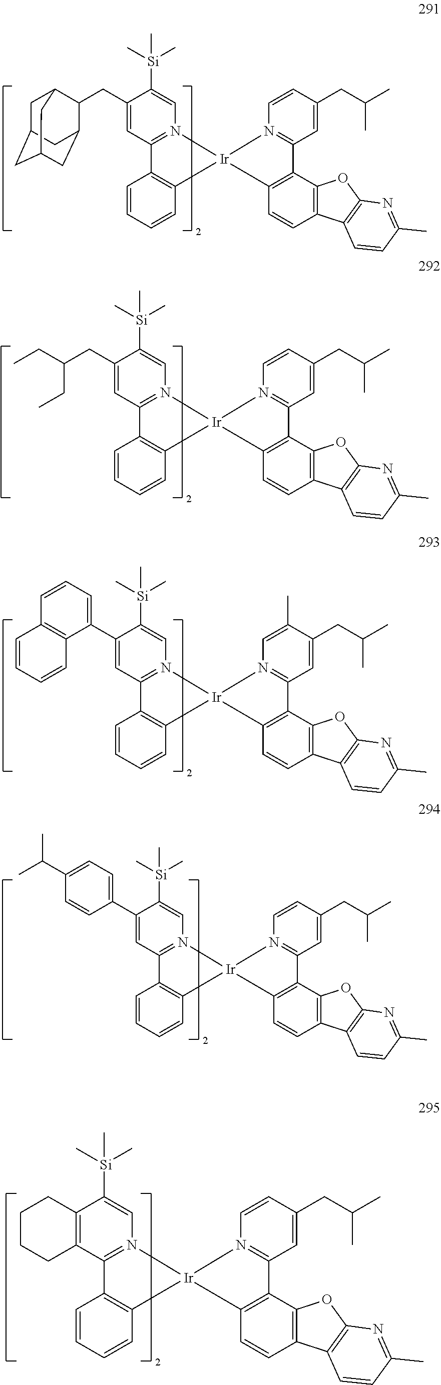

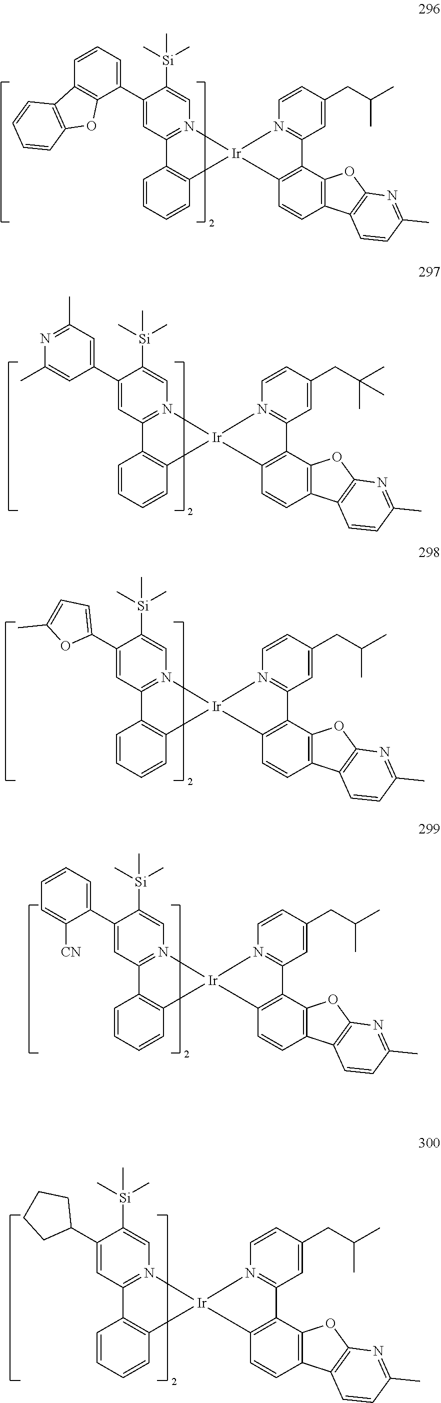

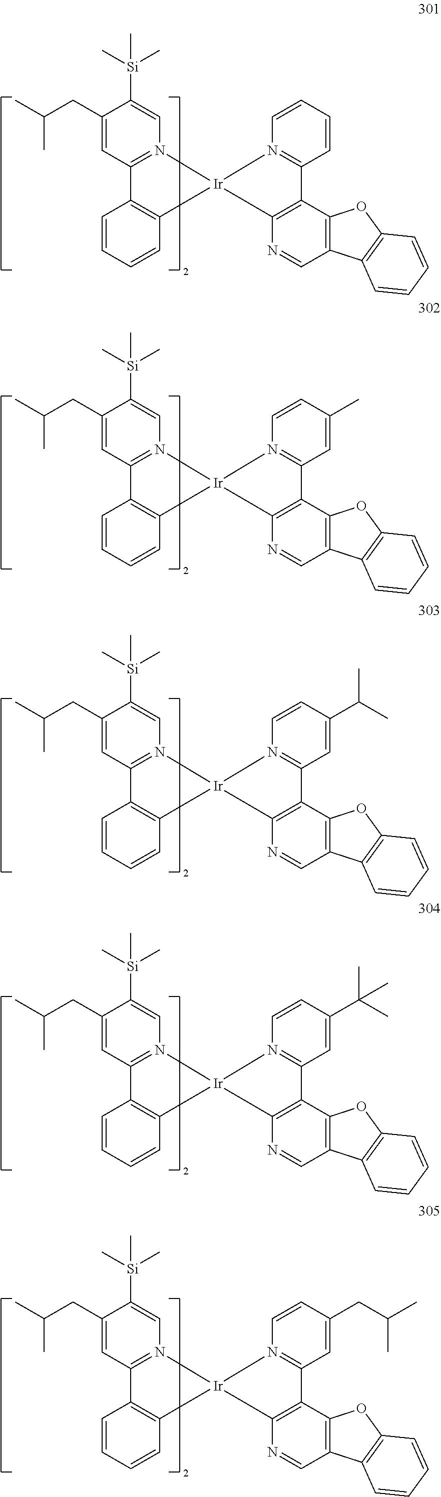

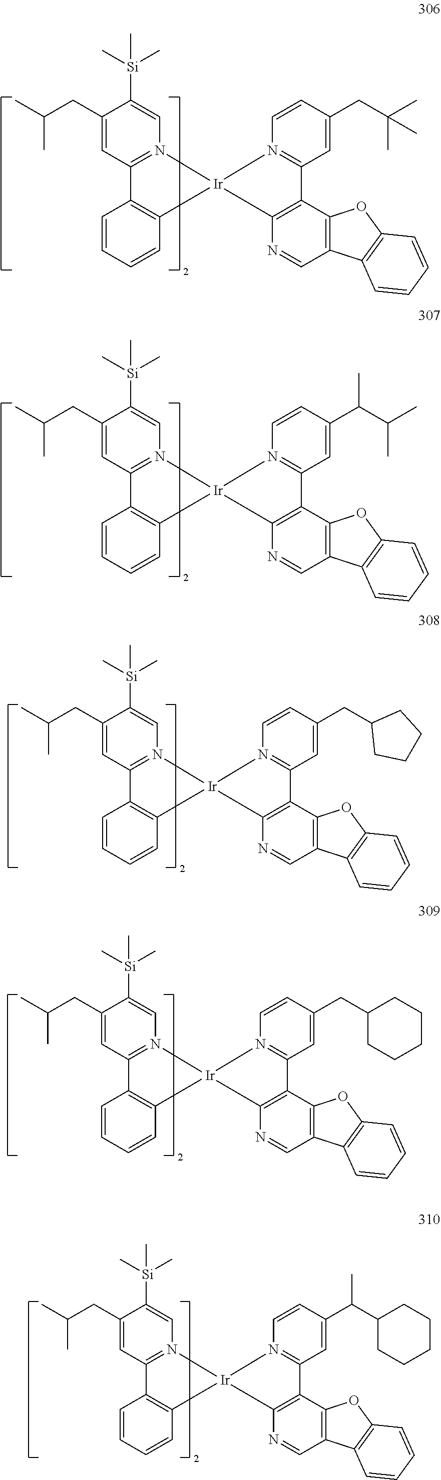

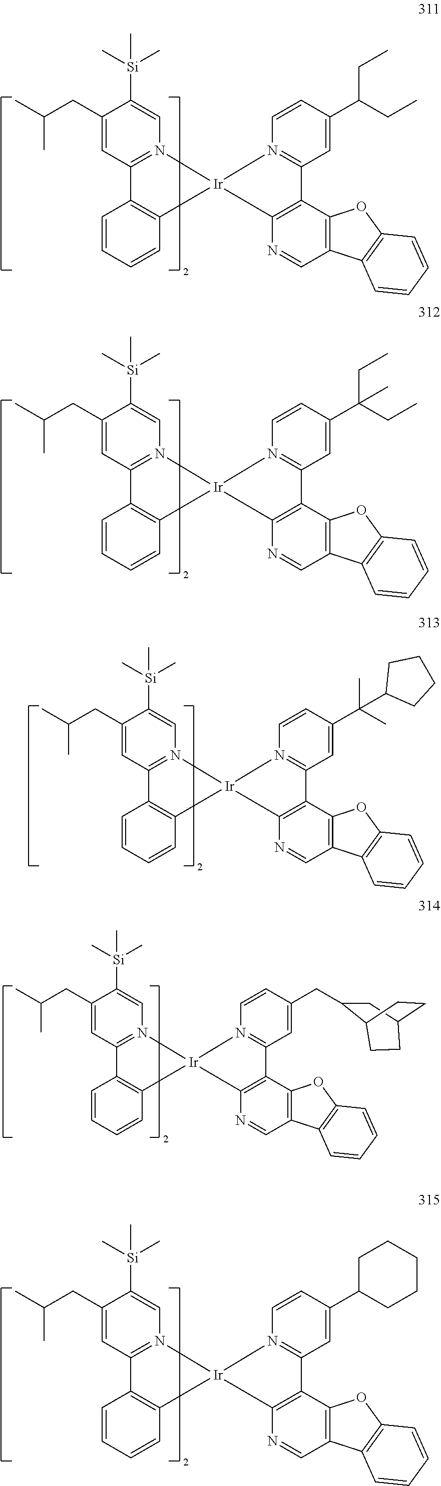

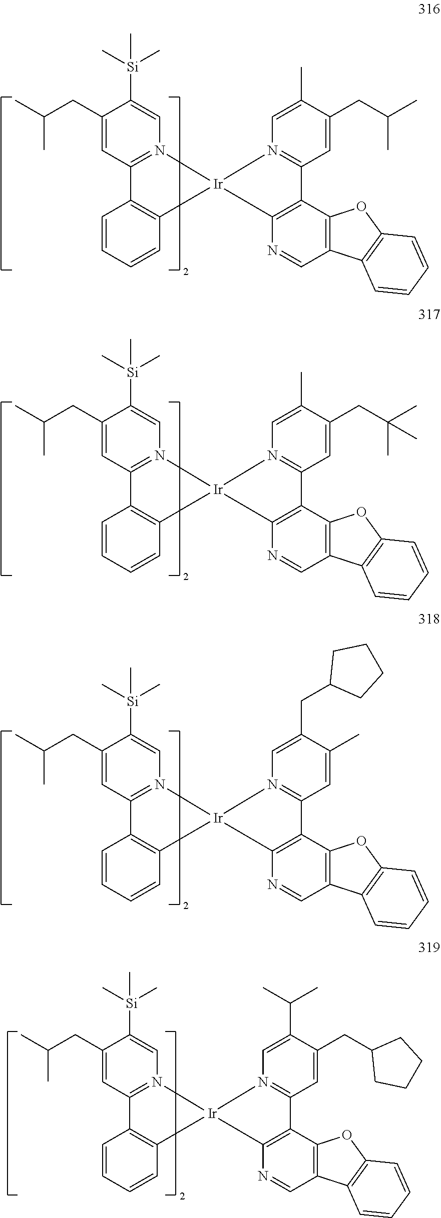

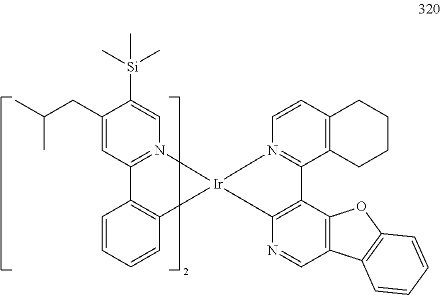

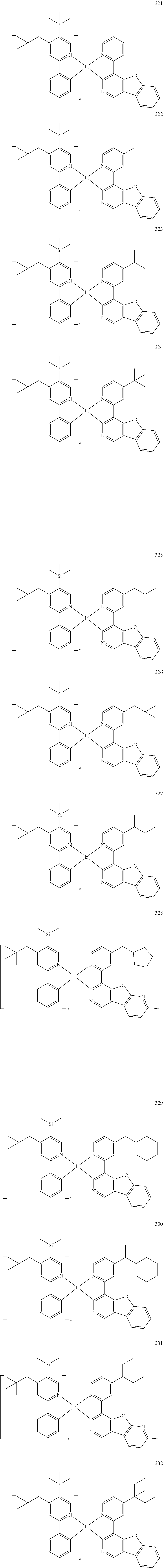

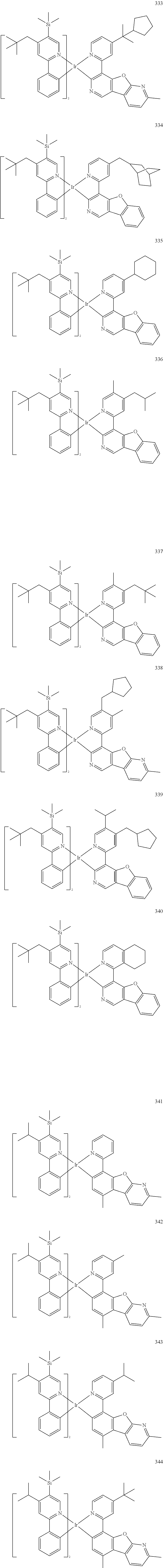

[chemical structure]

[chemical structure]

[chemical structure]

[chemical structure]

[chemical structure]

[chemical structure]

[chemical structure]

[chemical structure]

[chemical structure]

[chemical structure]

[chemical structure]

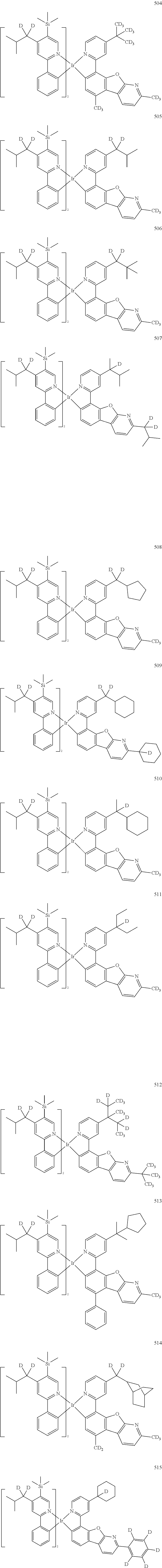

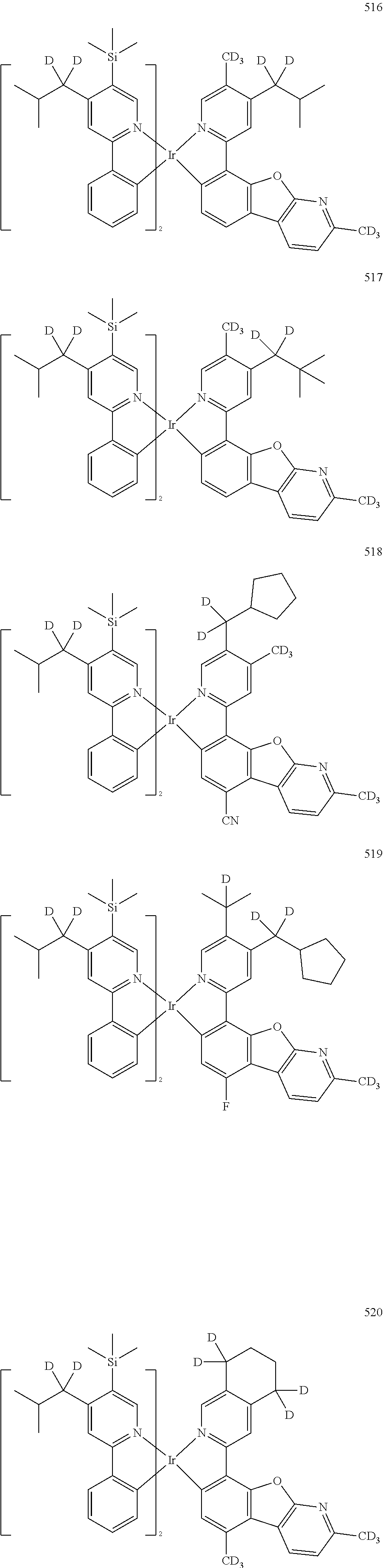

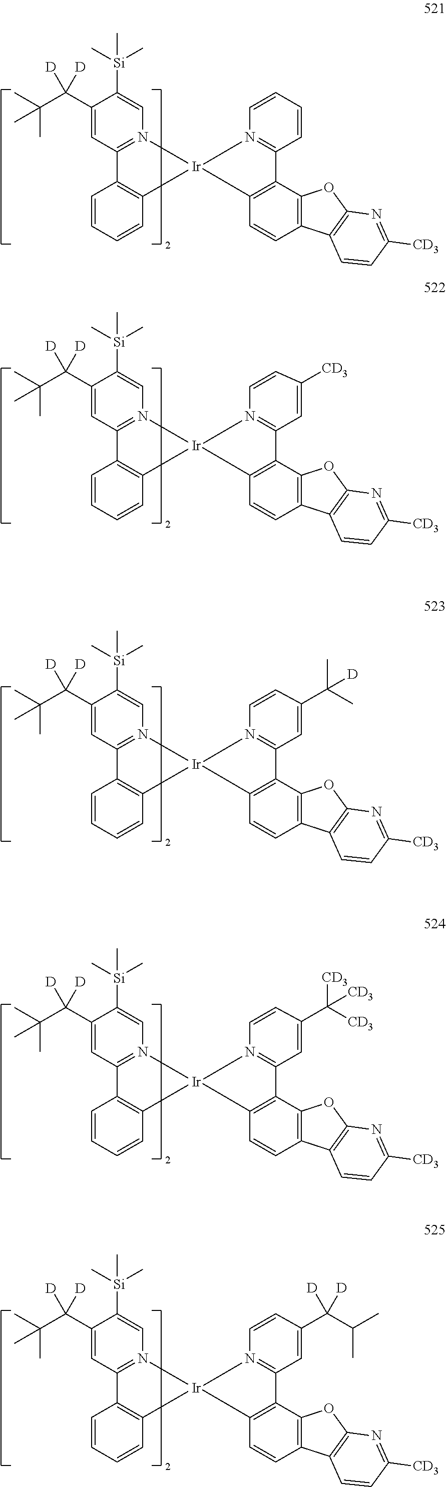

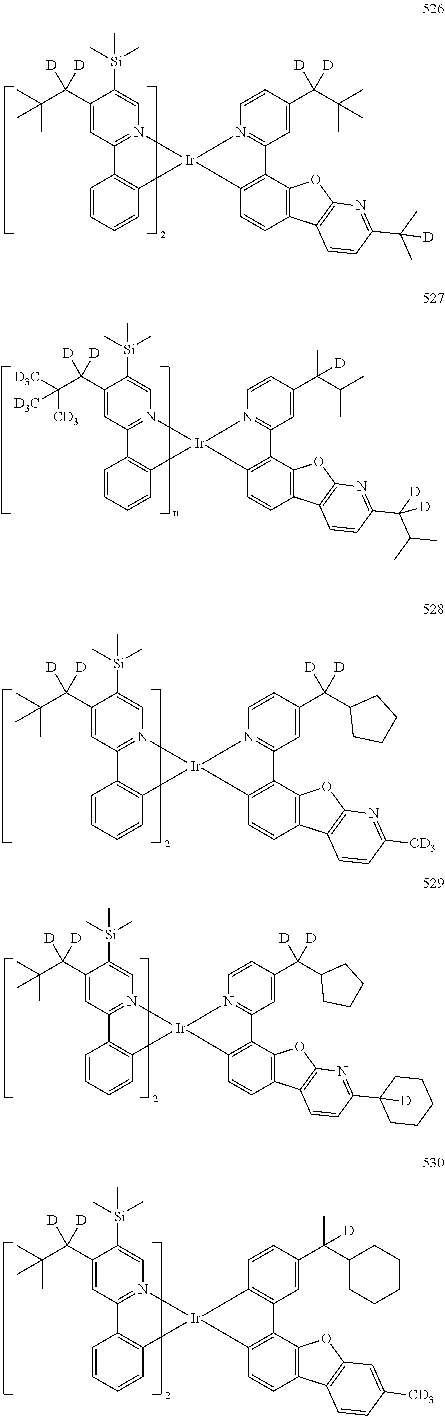

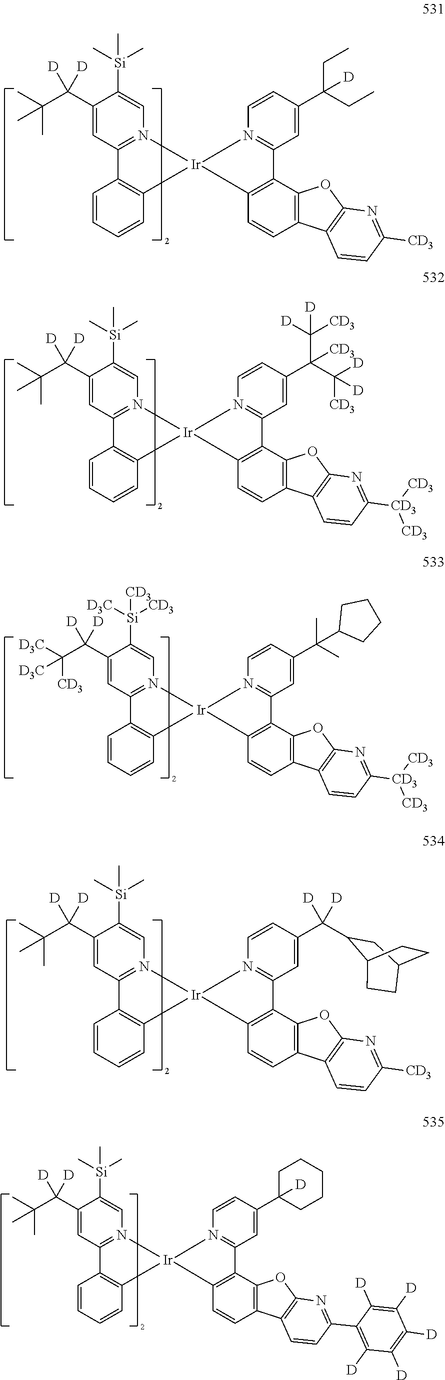

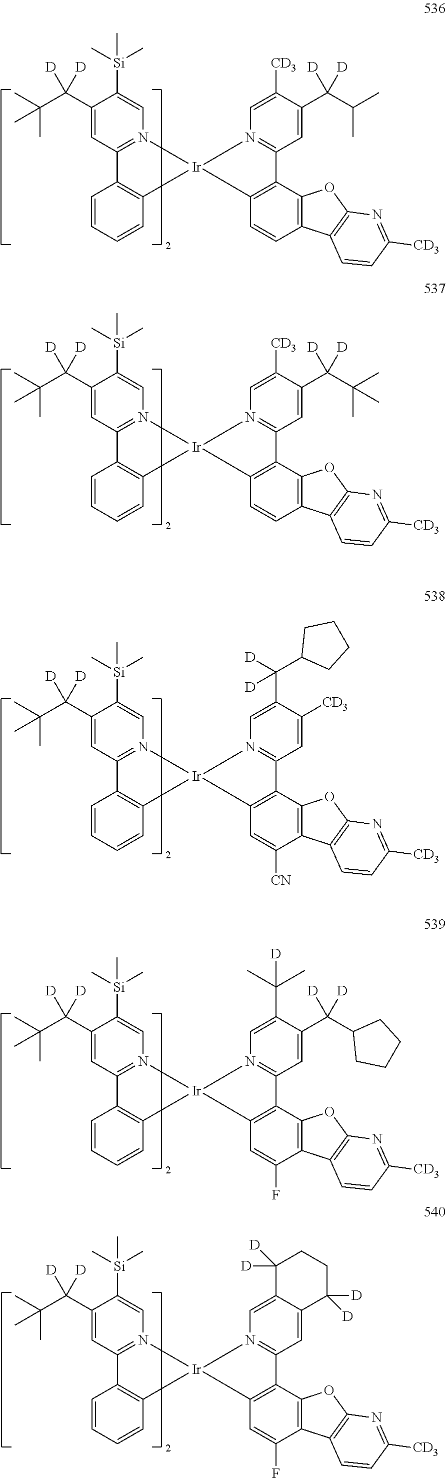

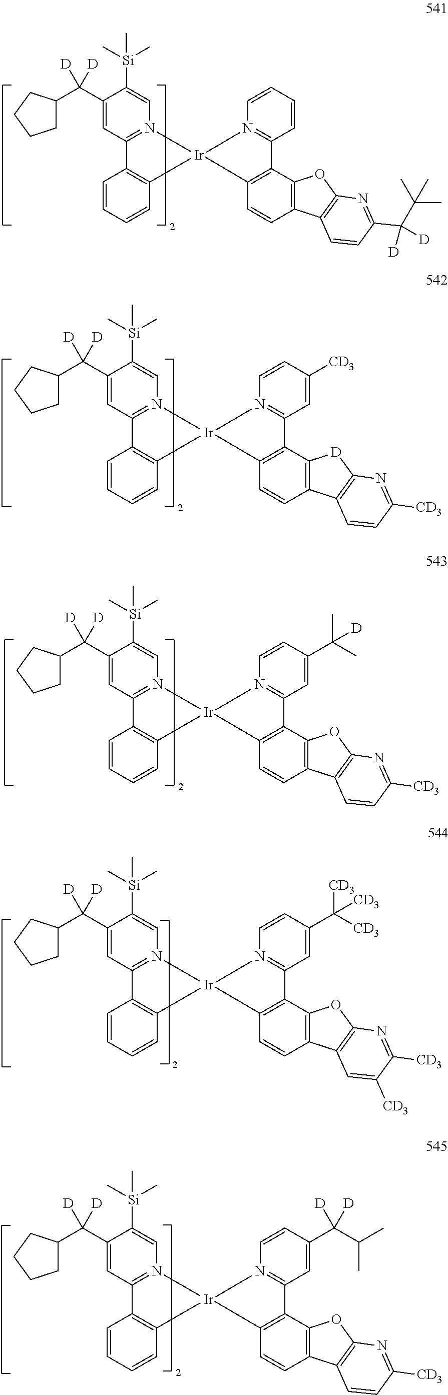

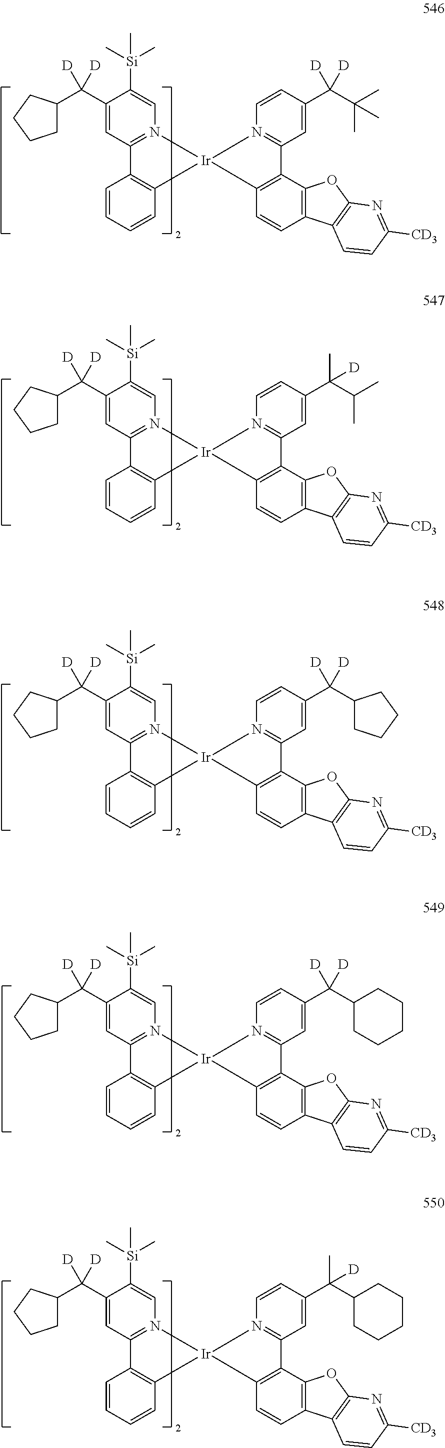

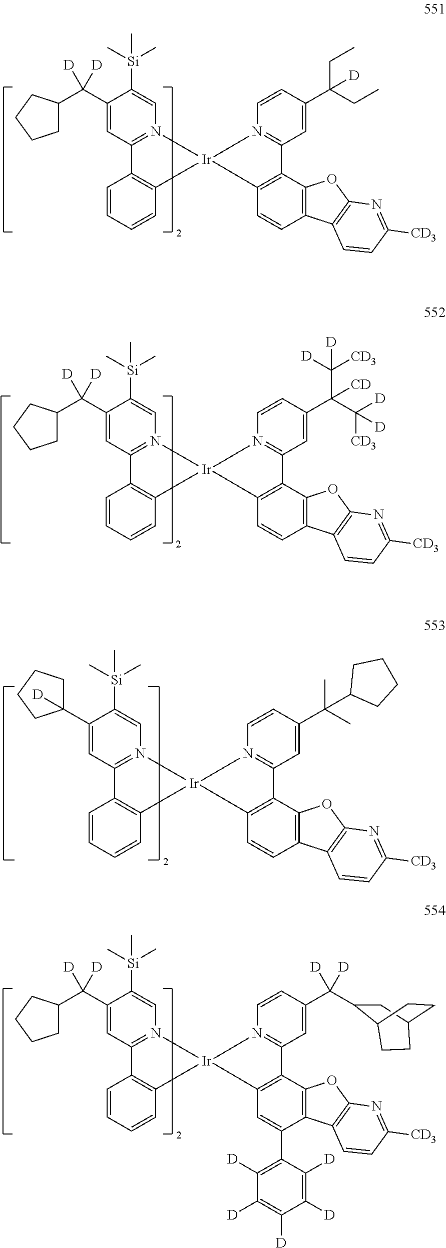

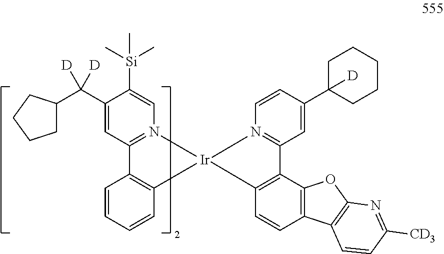

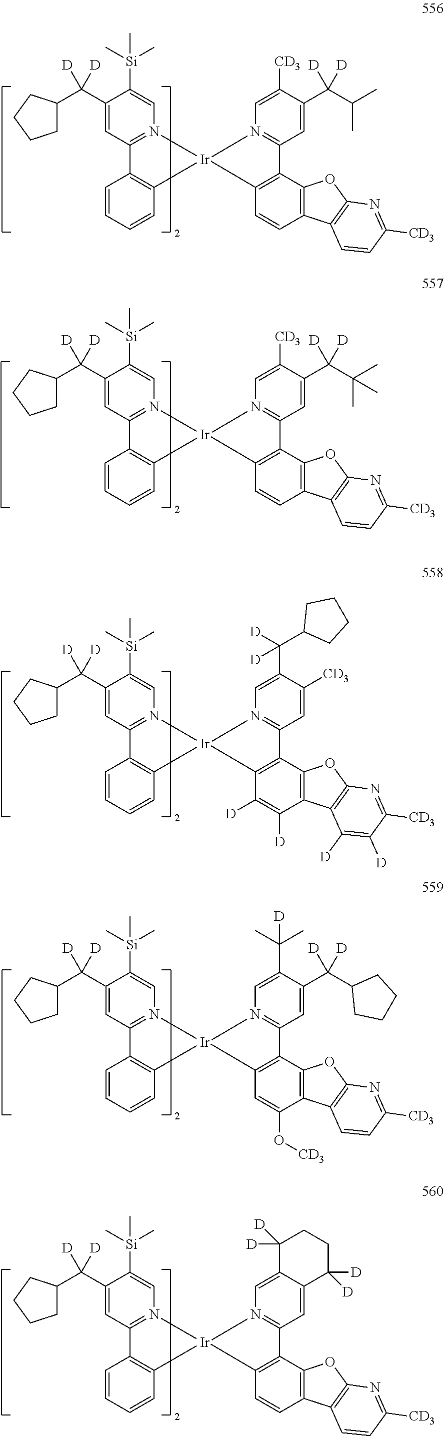

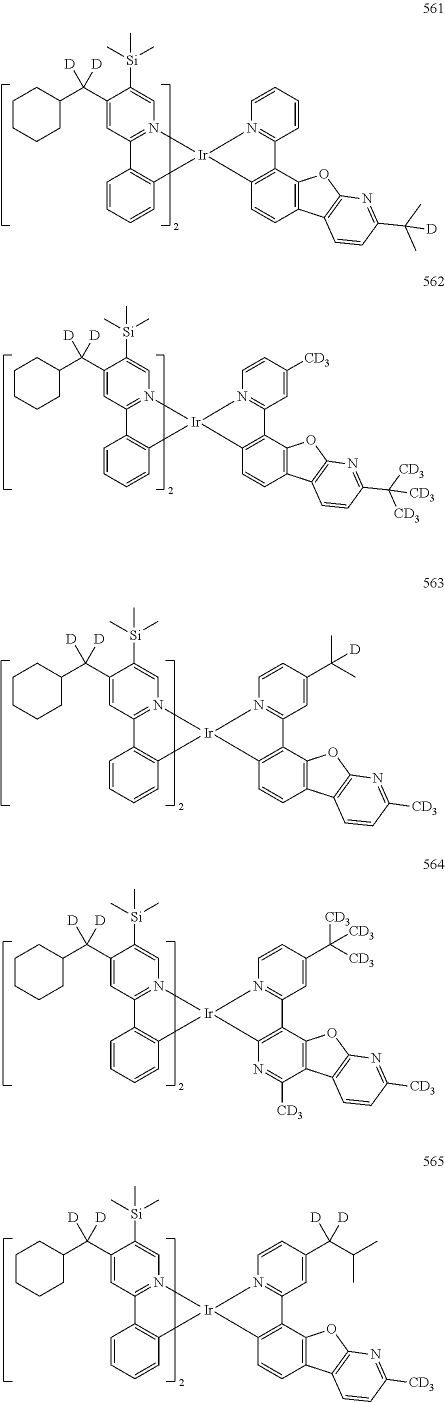

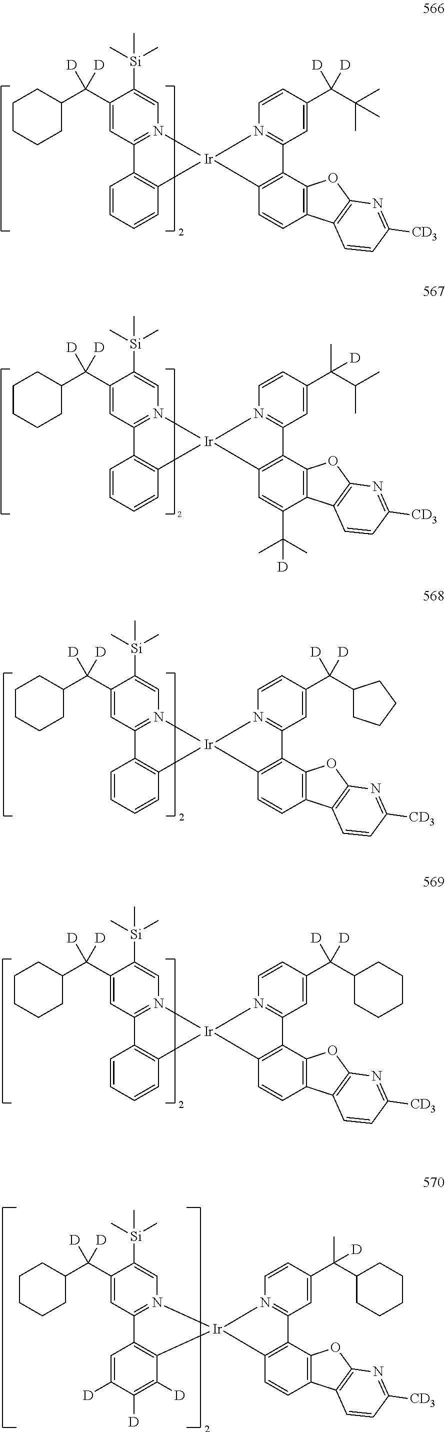

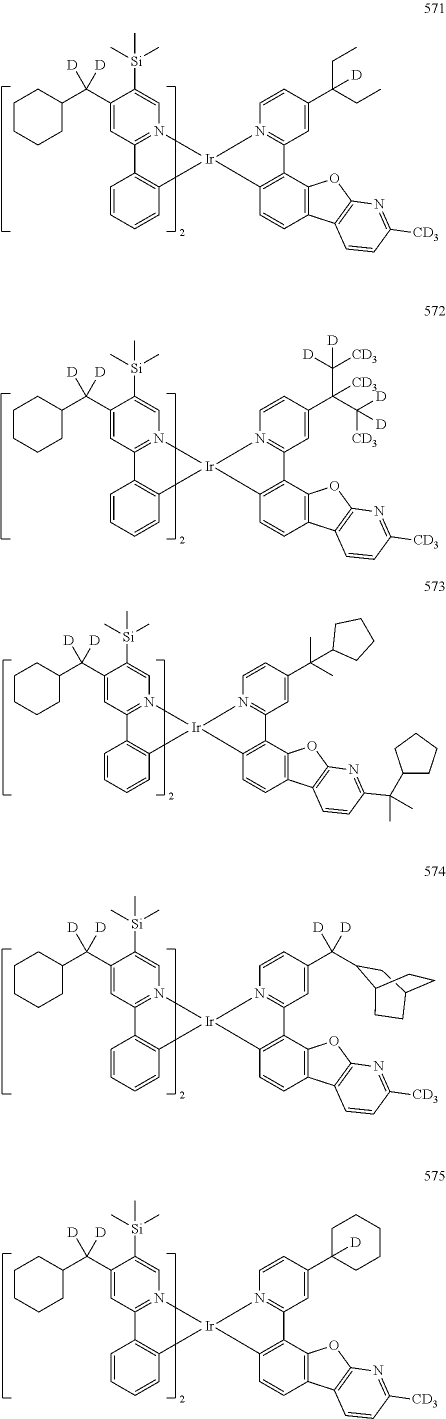

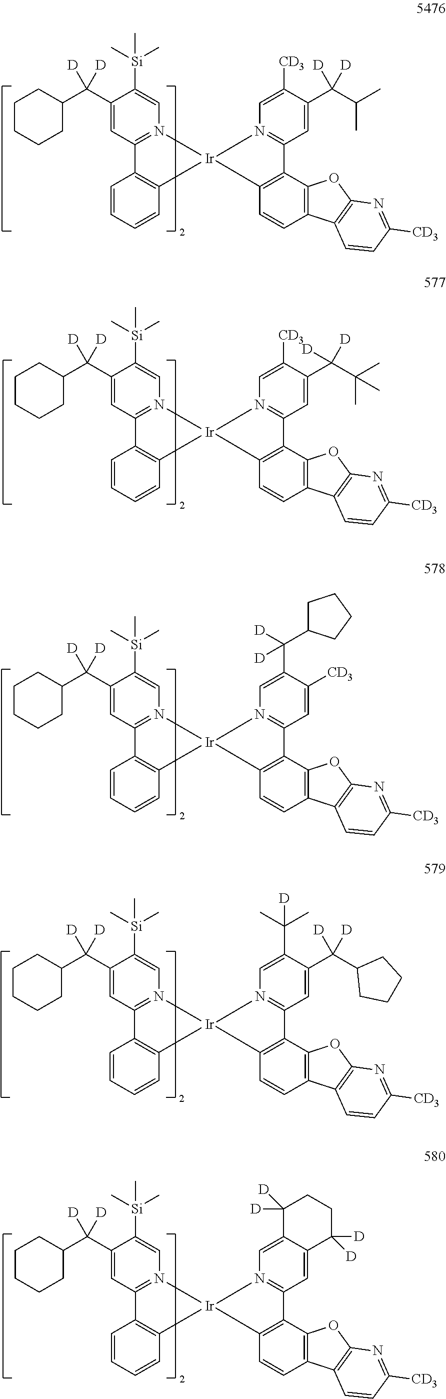

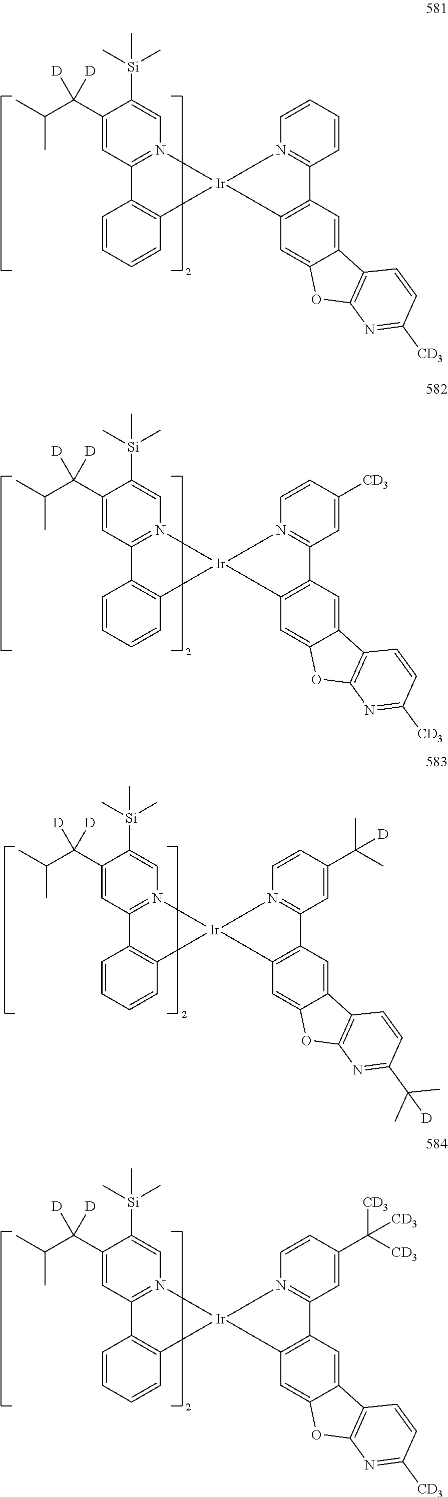

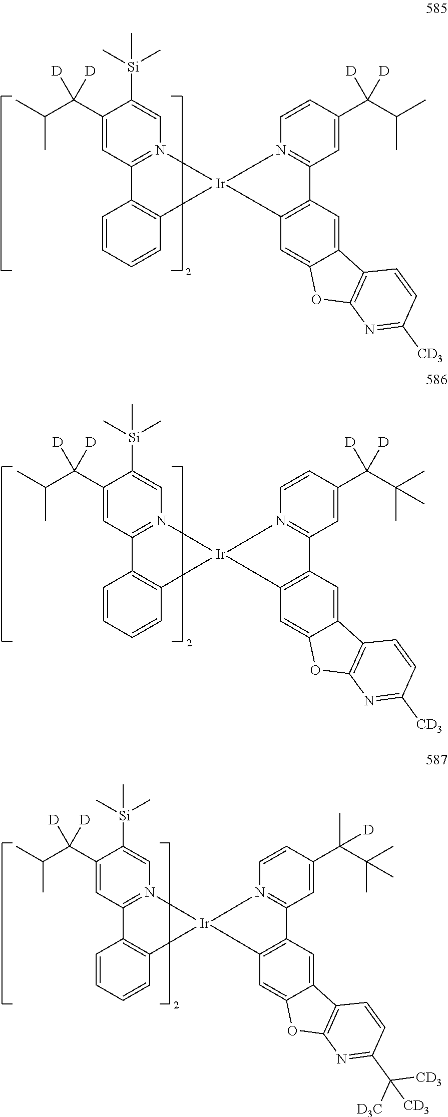

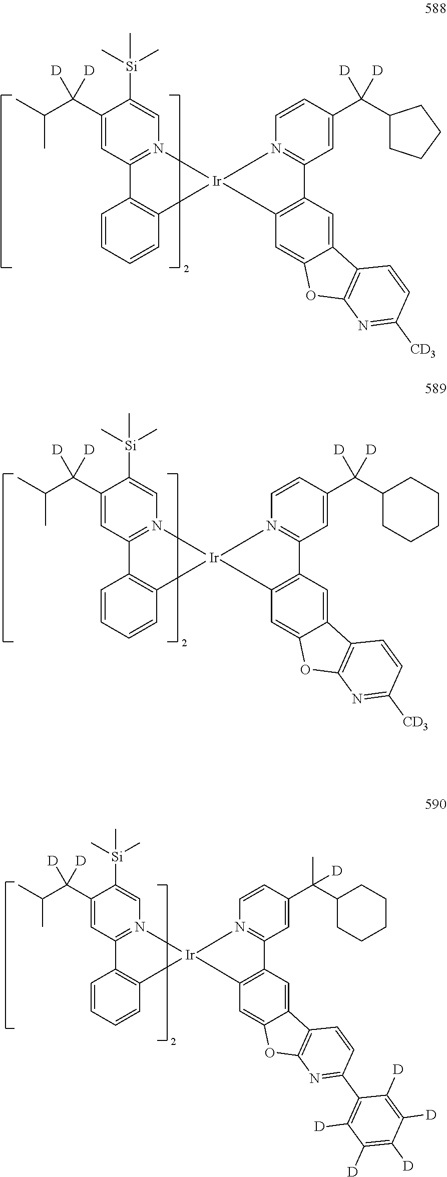

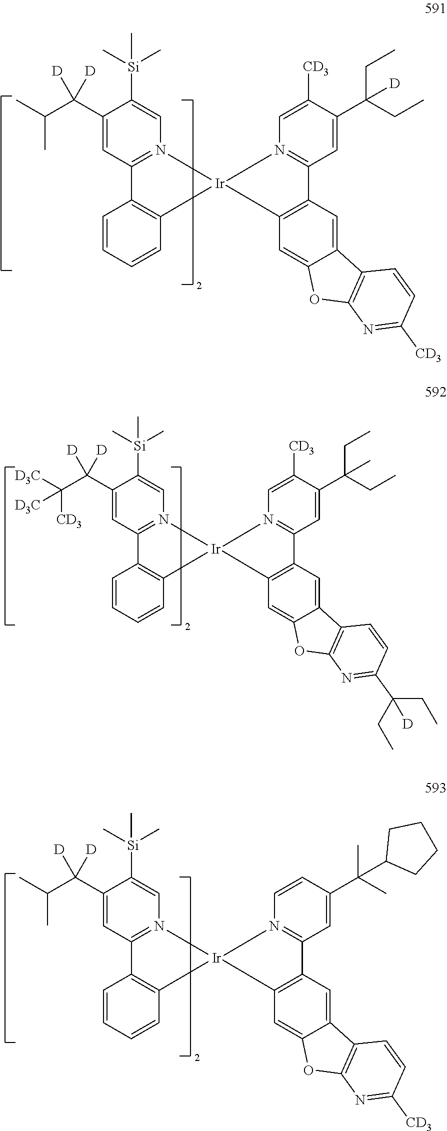

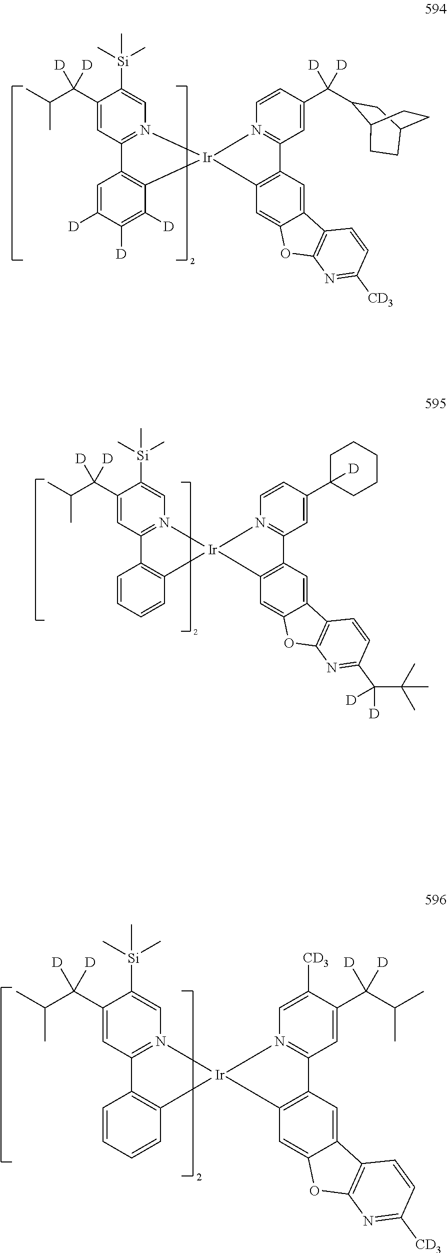

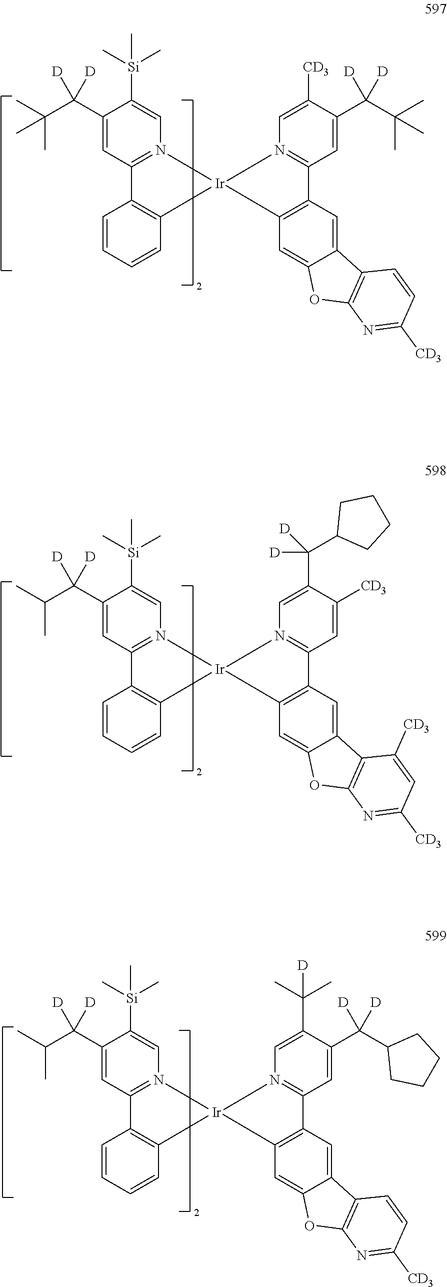

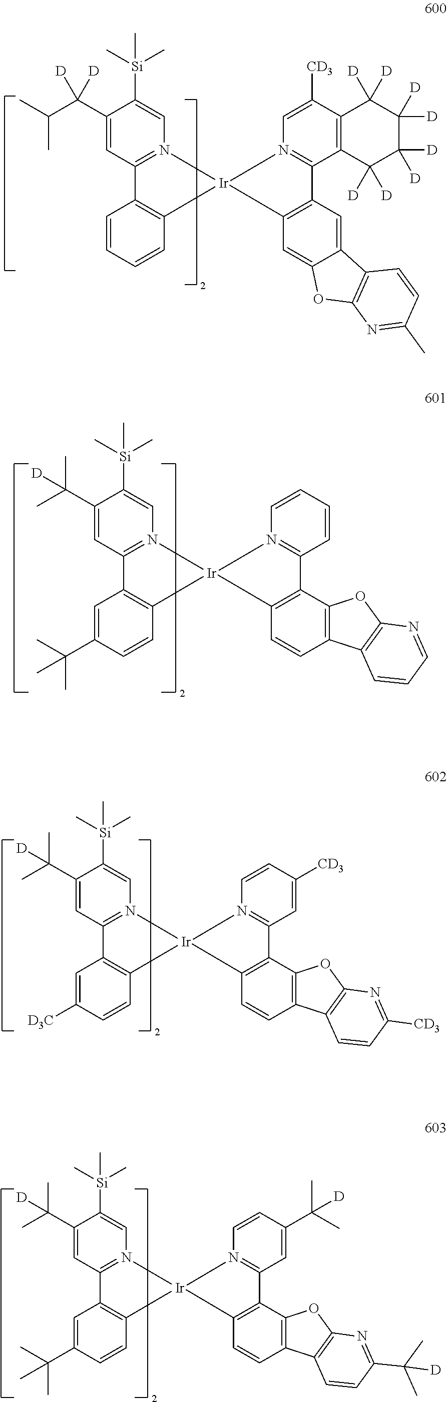

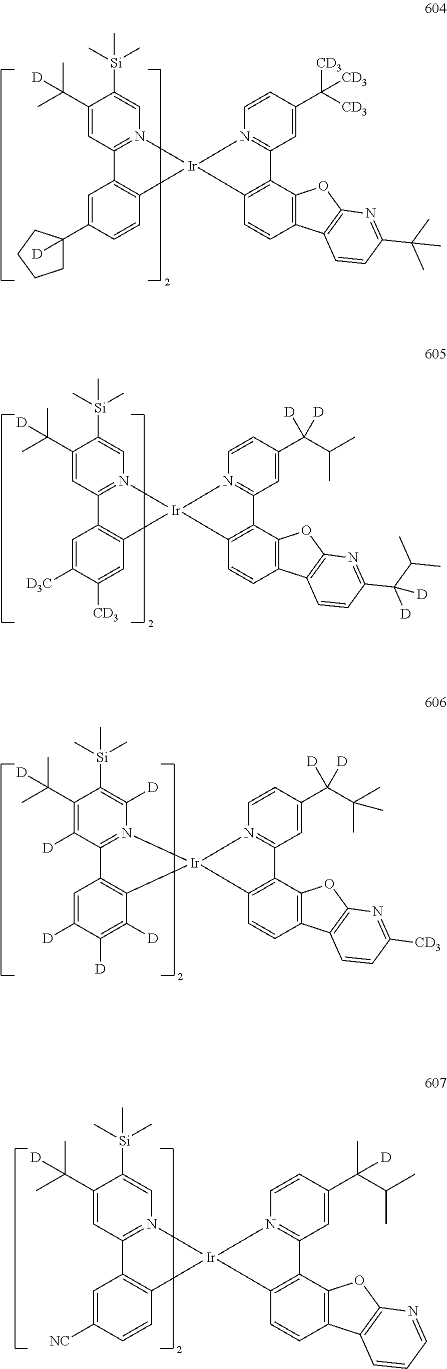

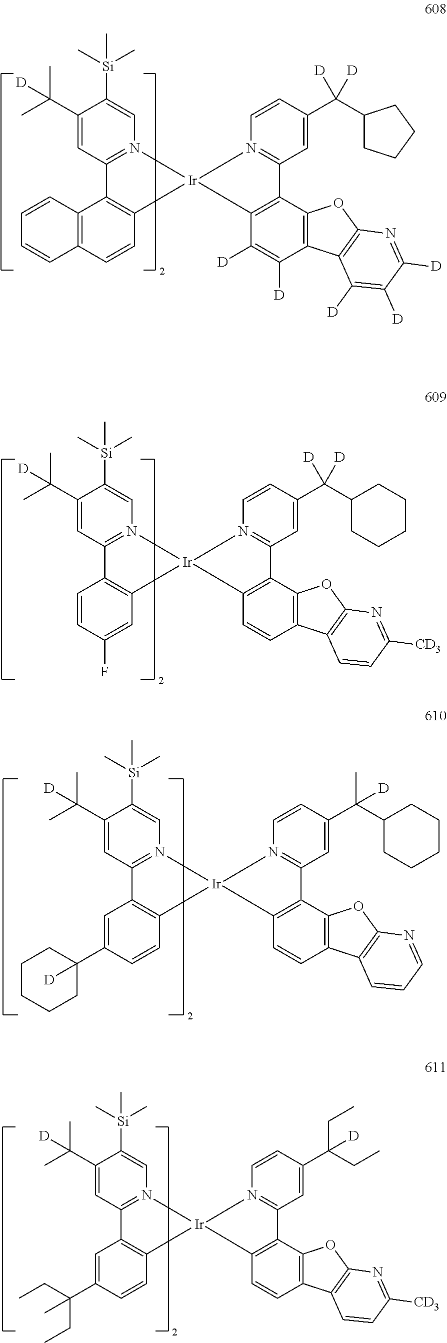

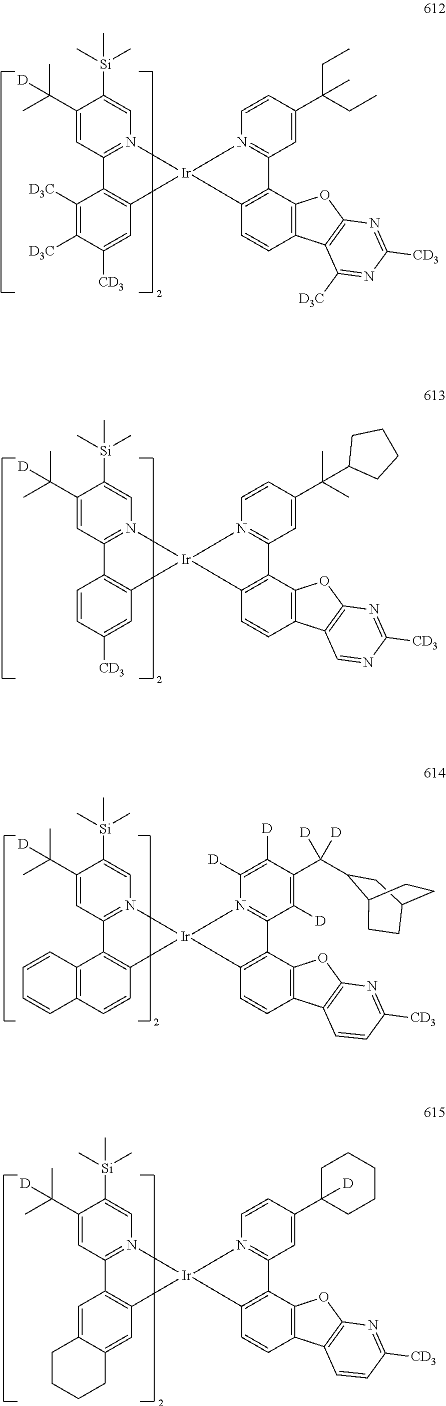

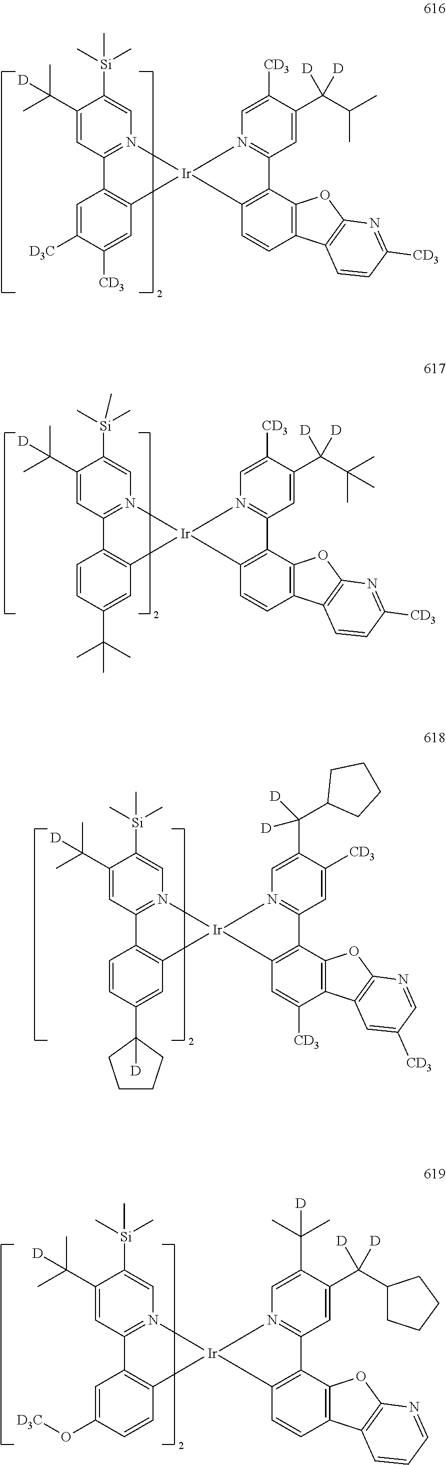

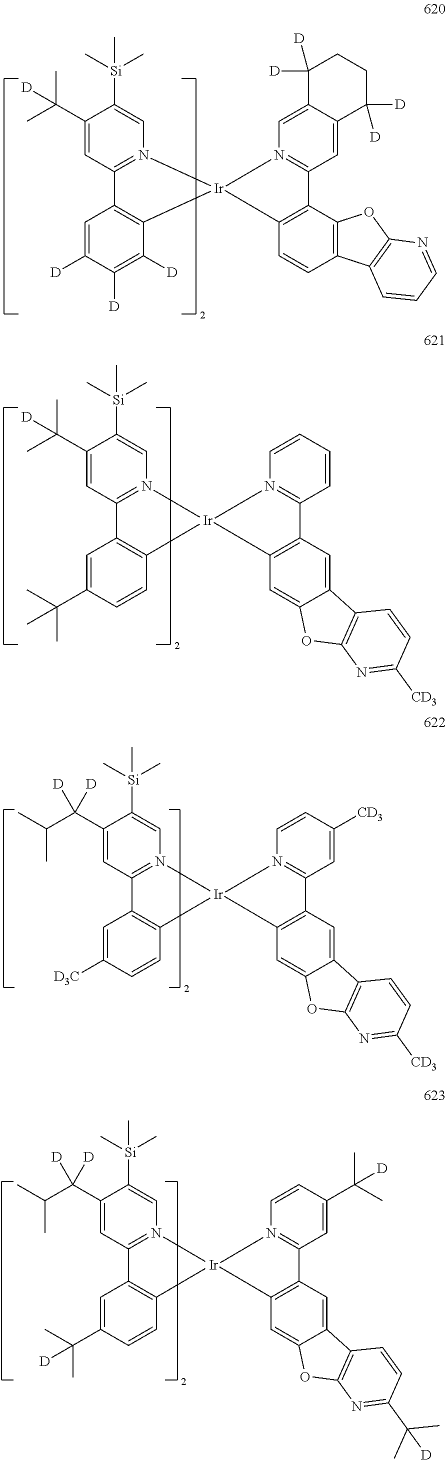

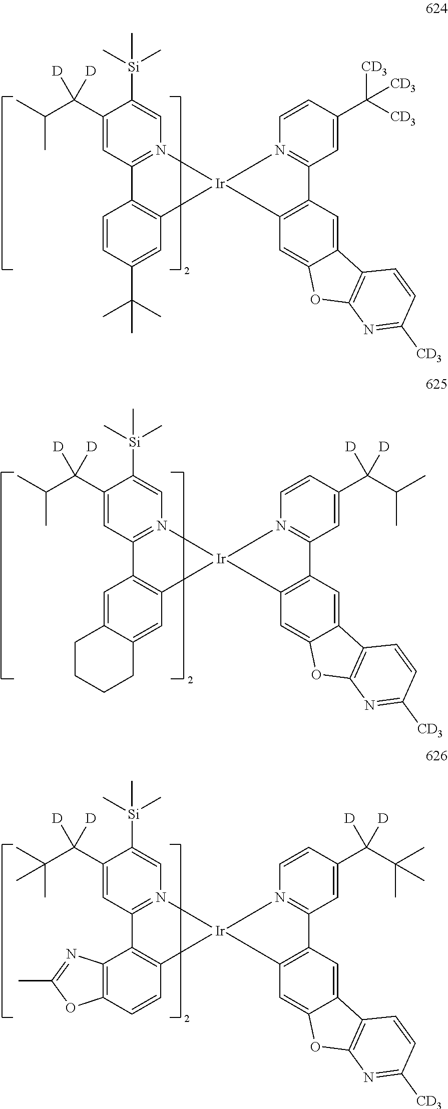

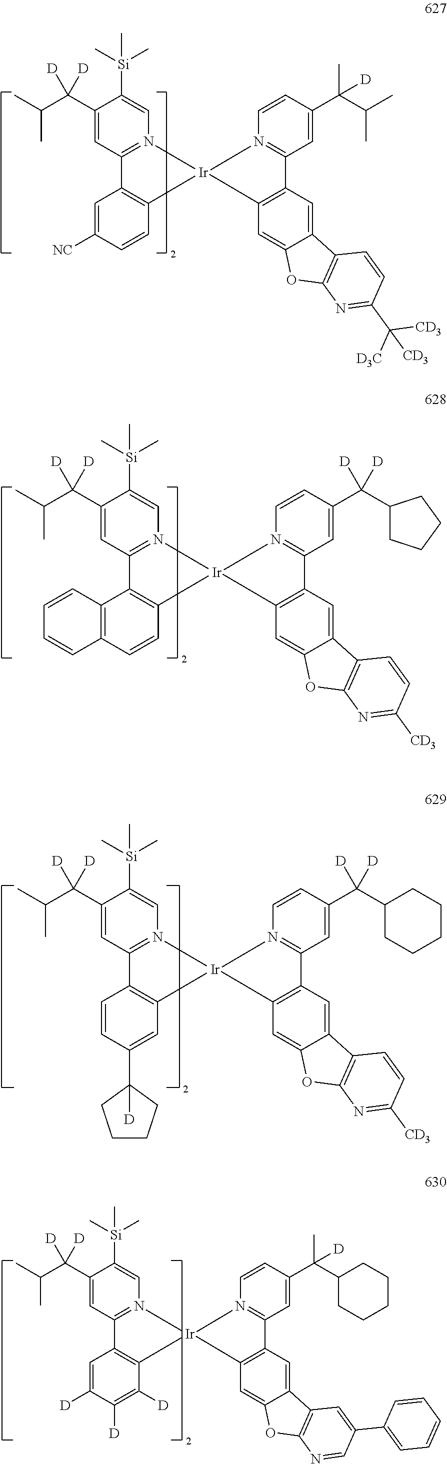

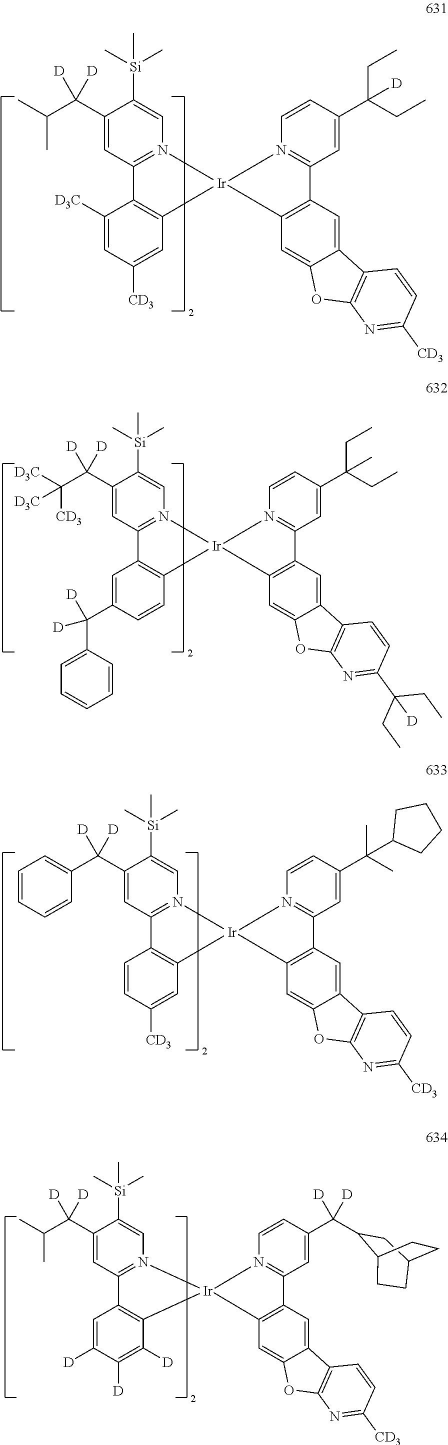

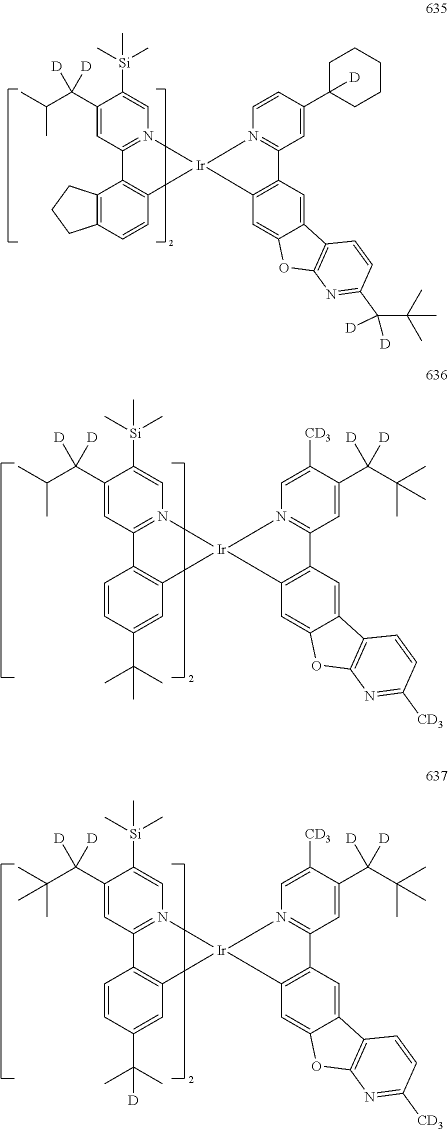

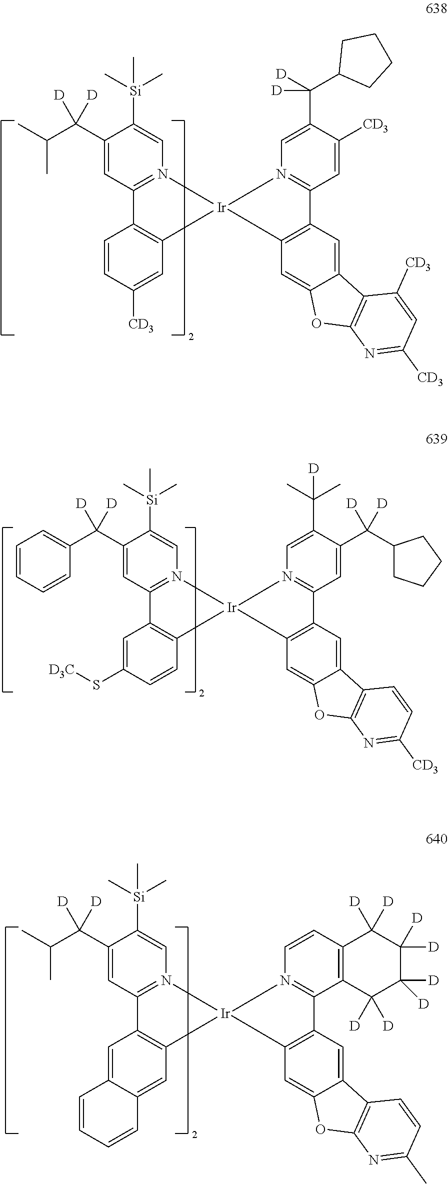

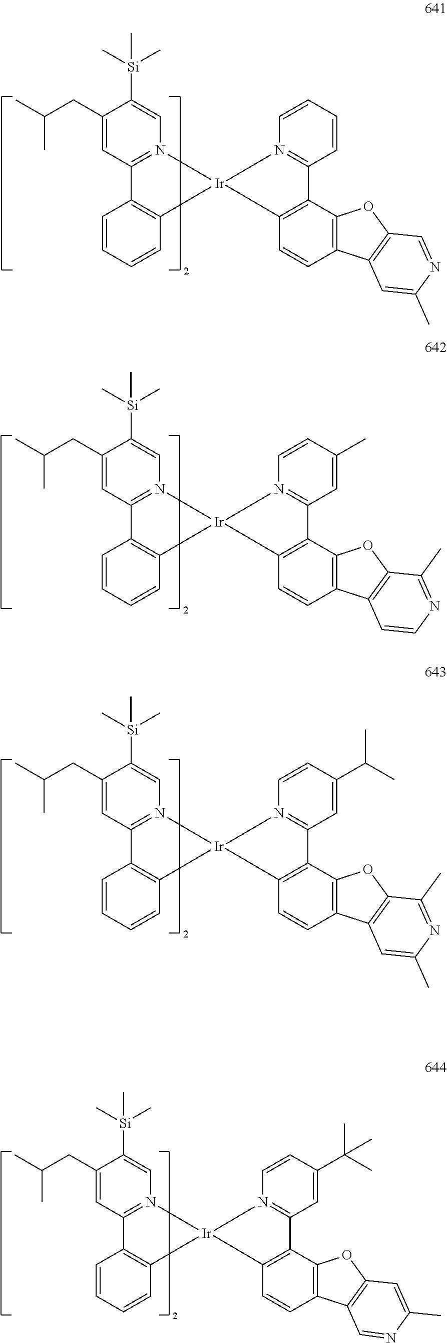

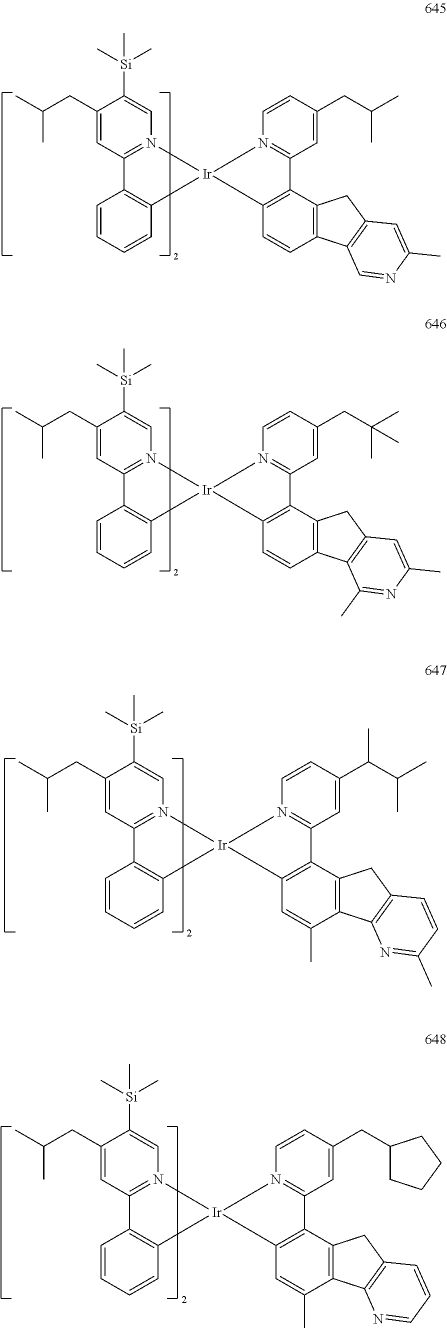

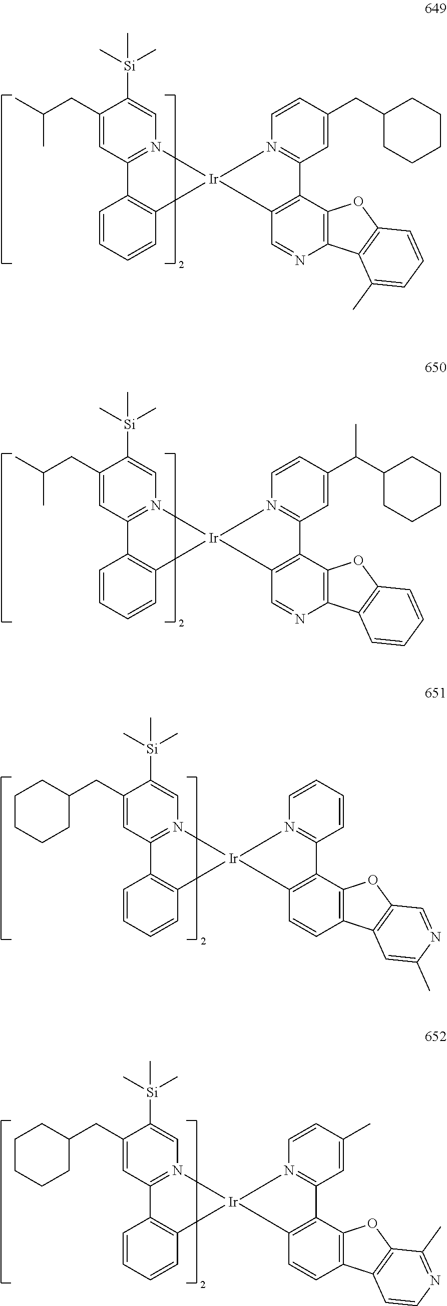

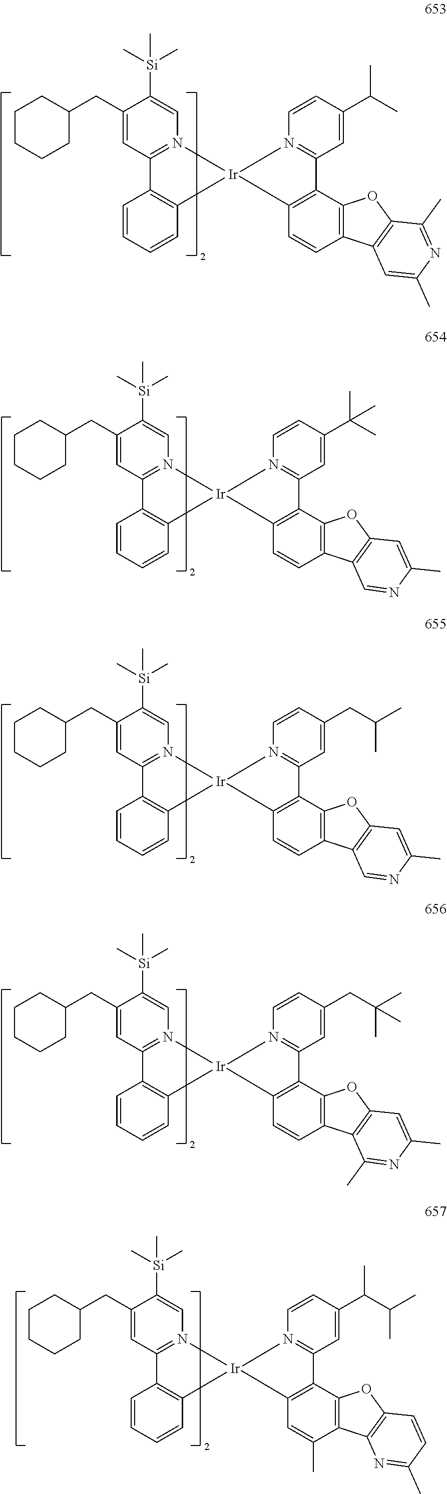

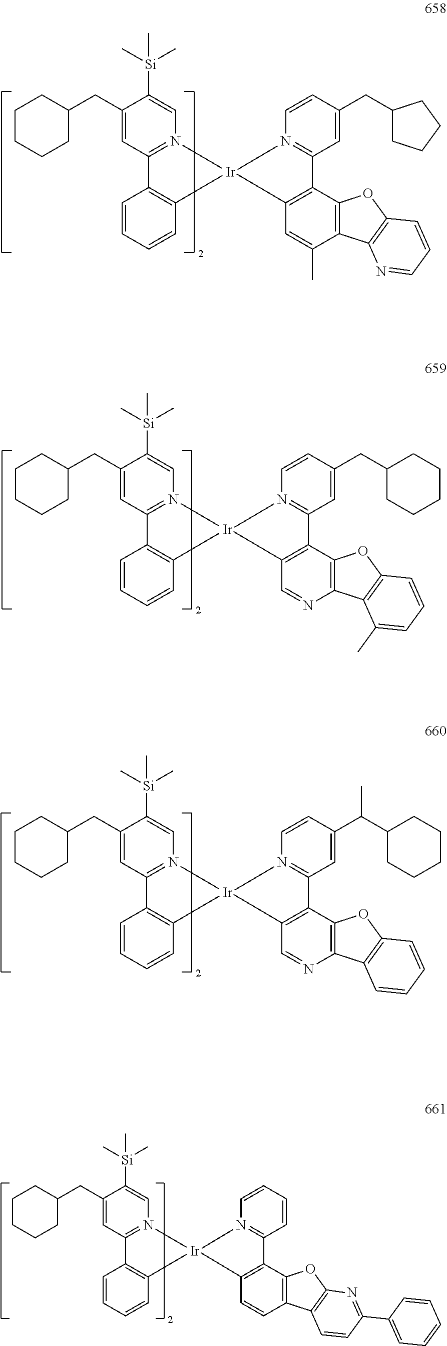

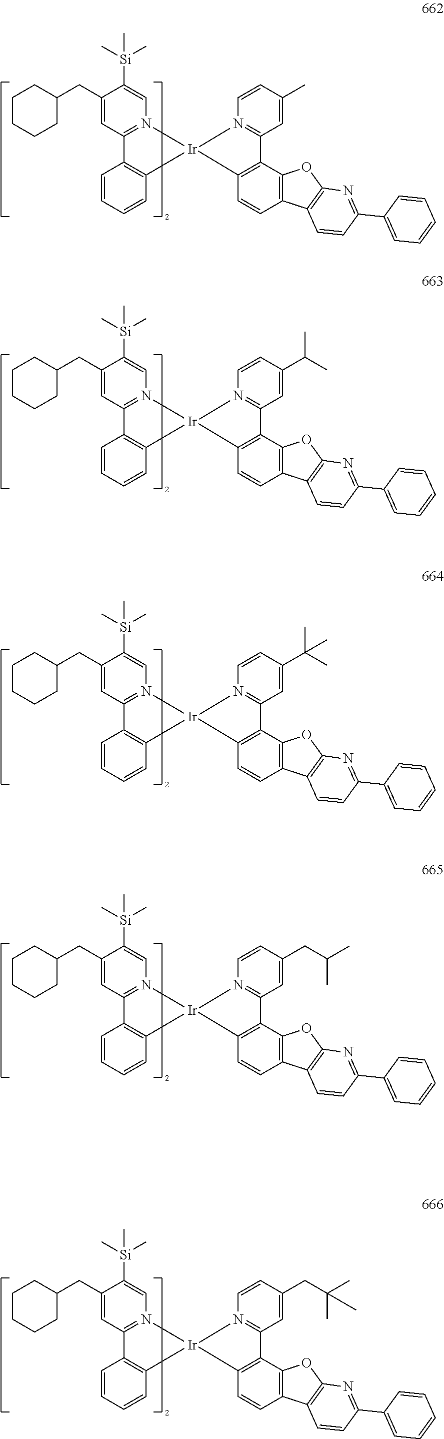

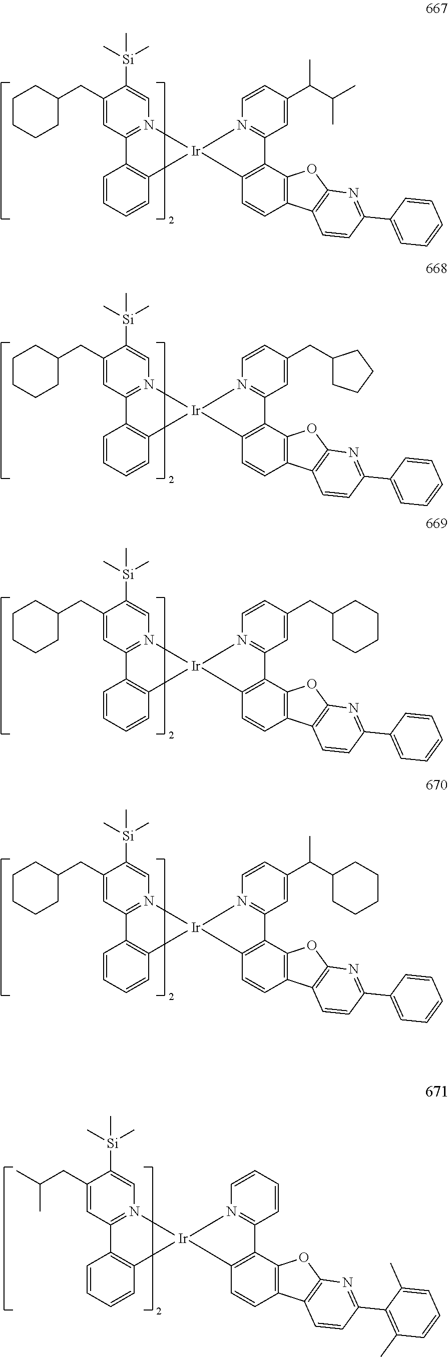

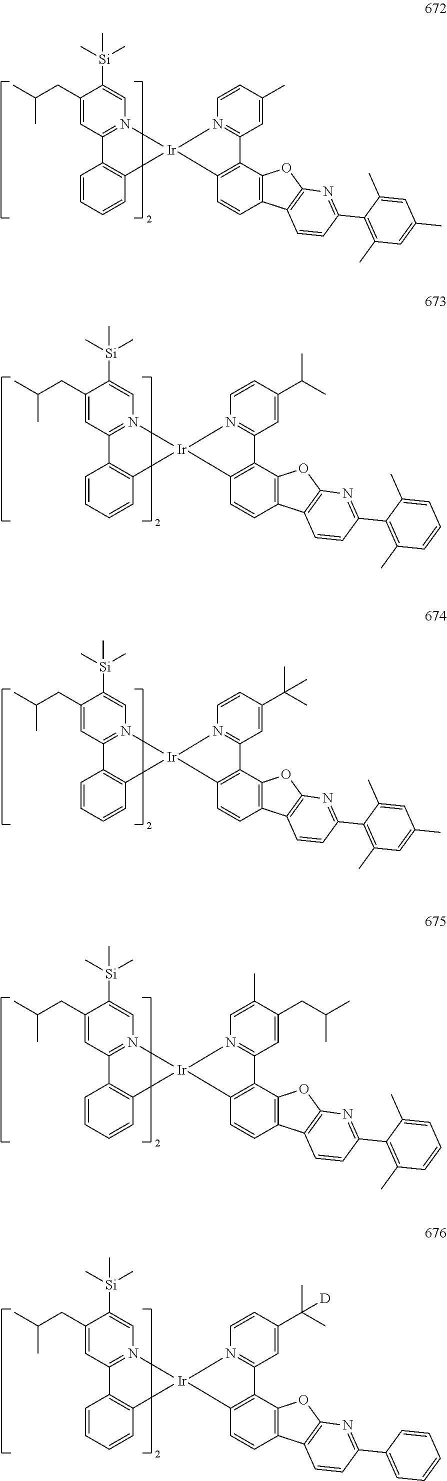

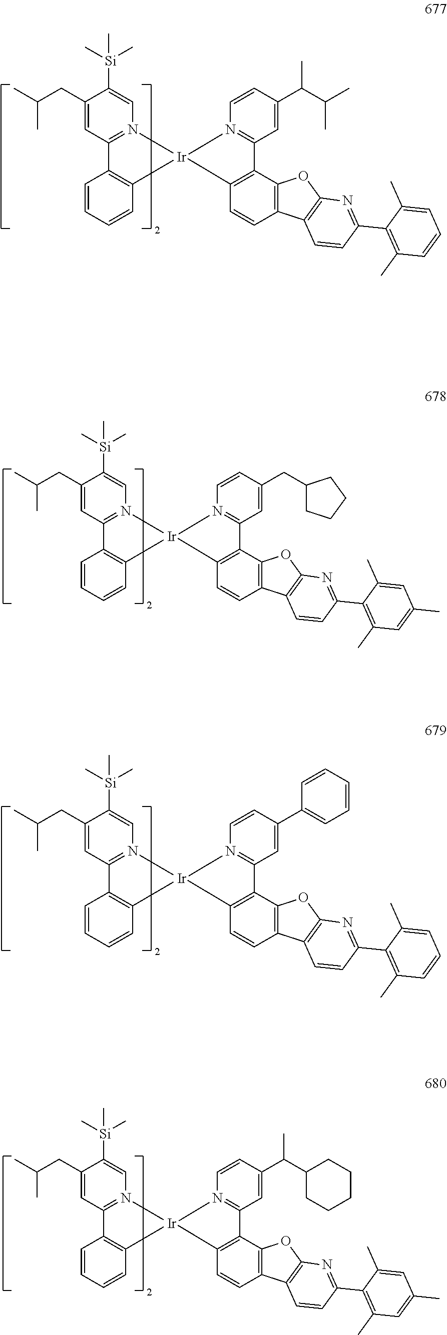

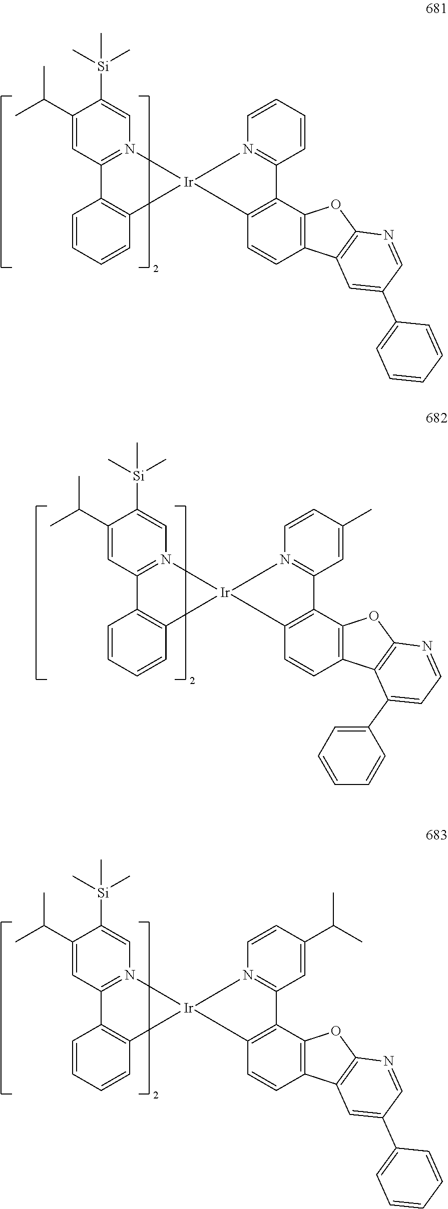

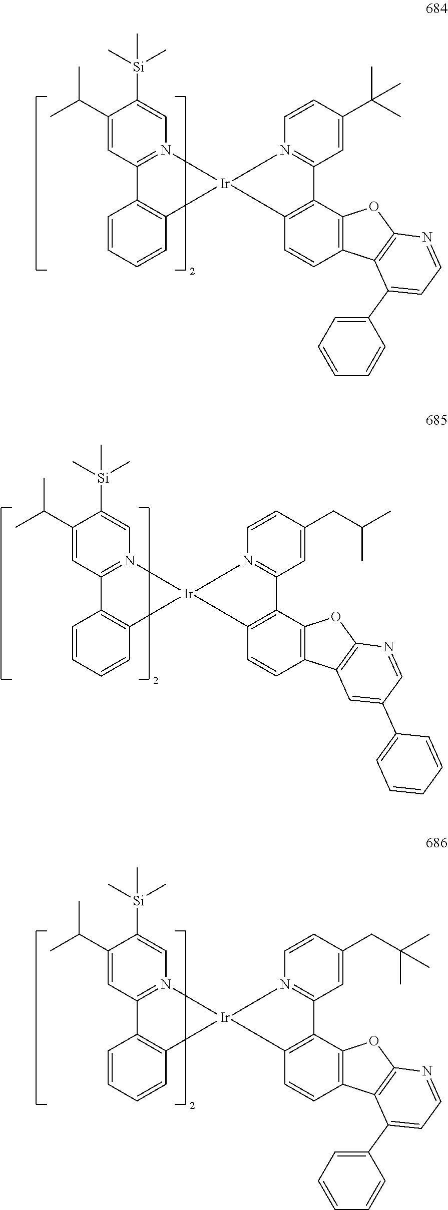

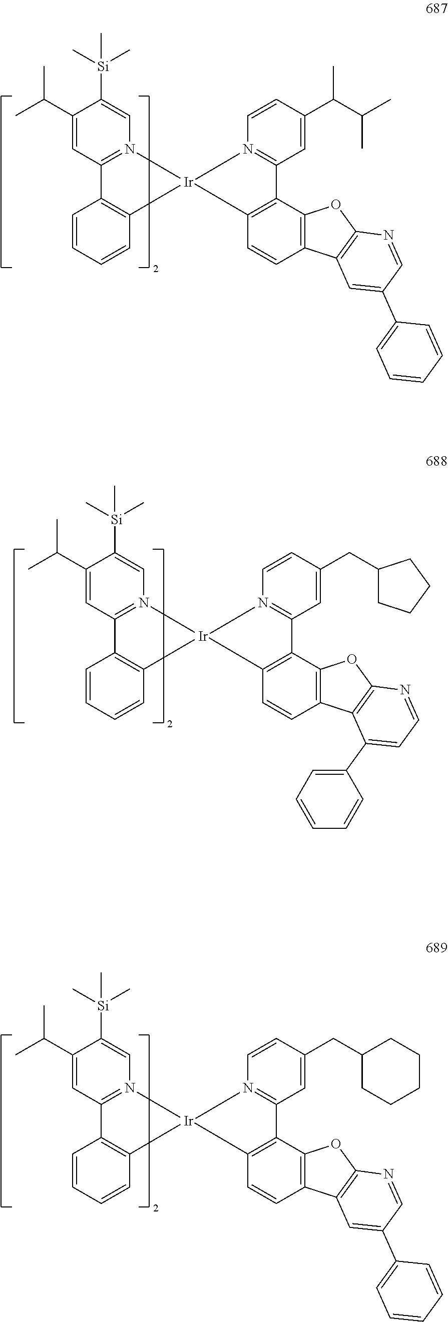

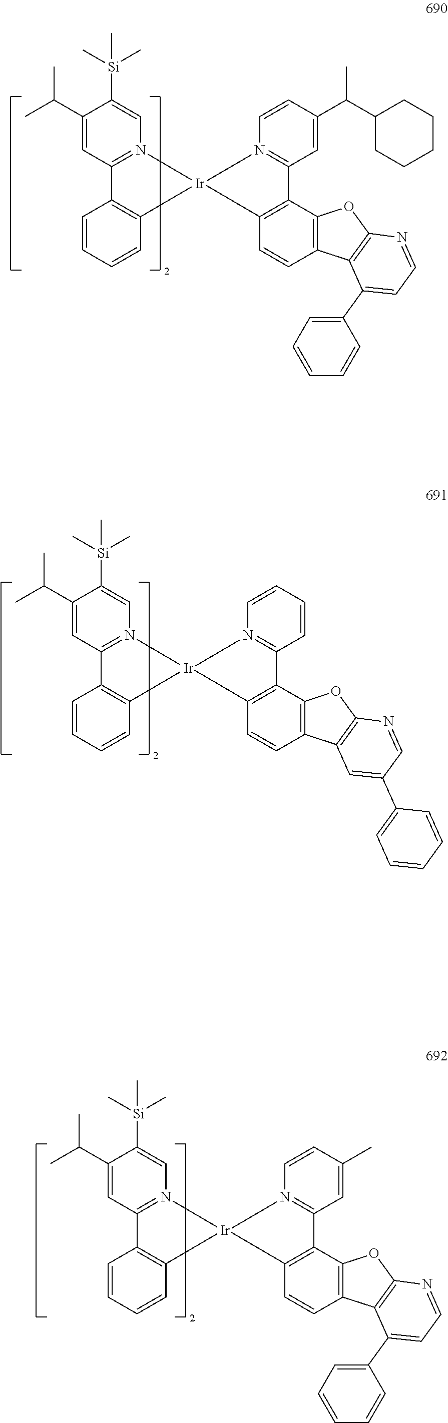

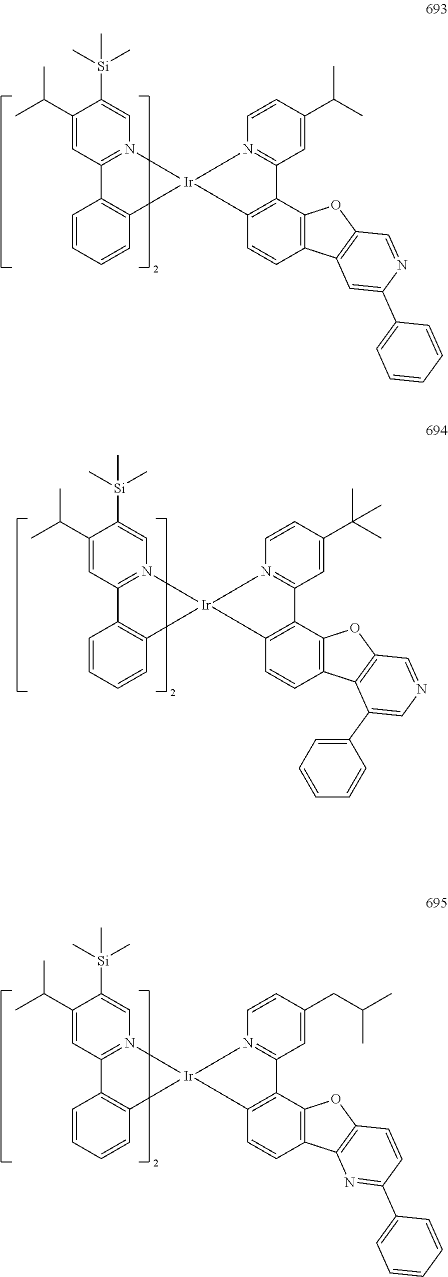

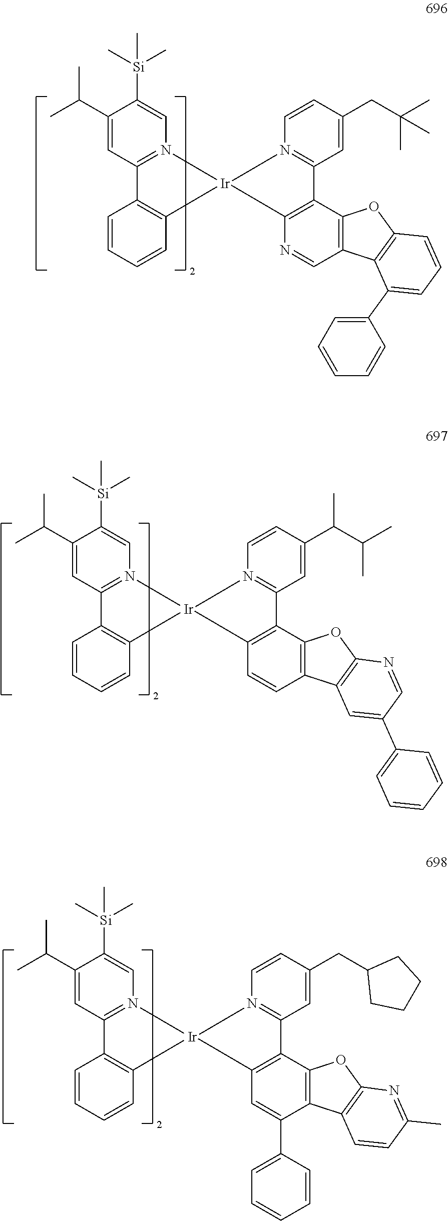

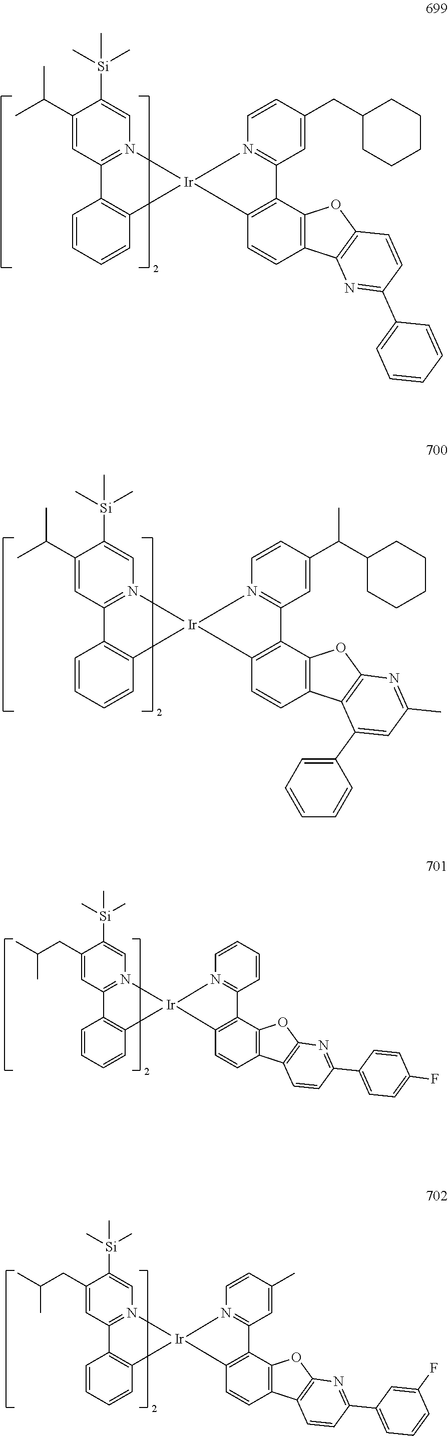

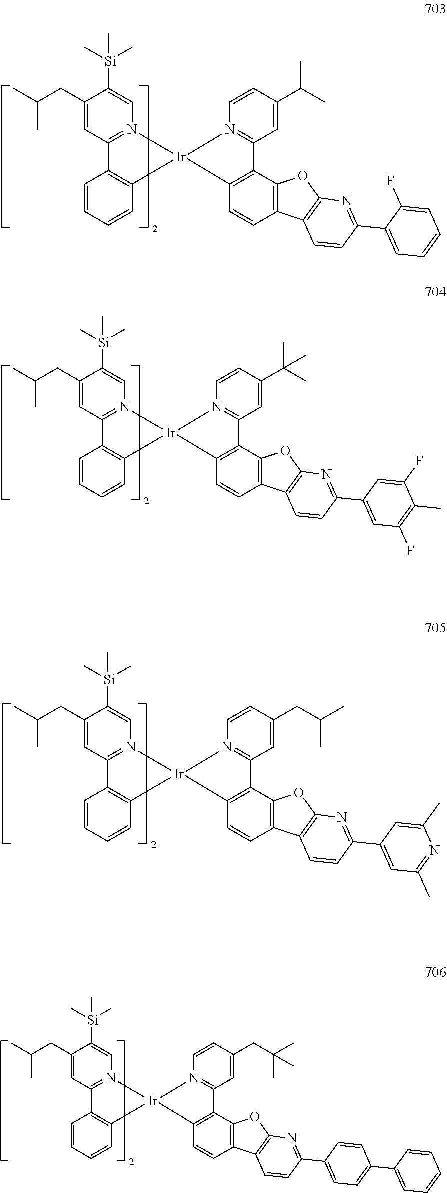

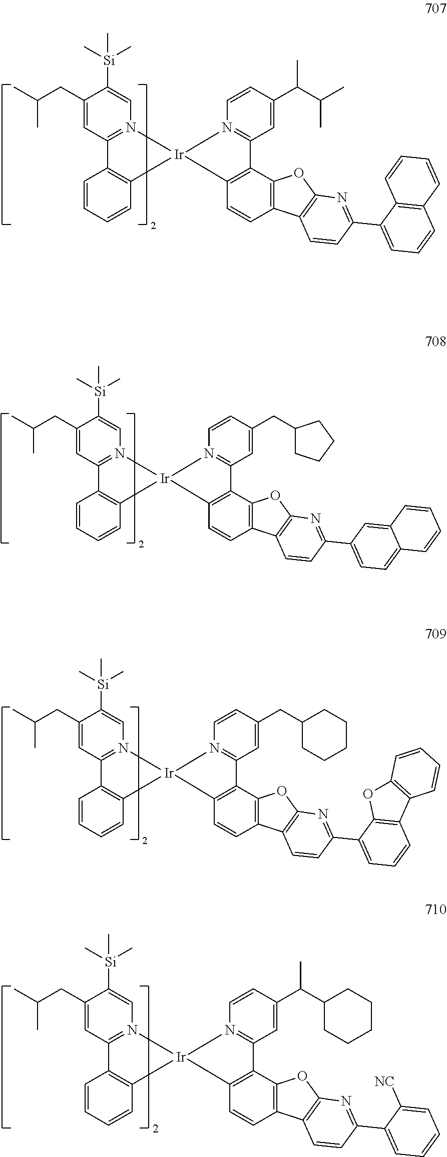

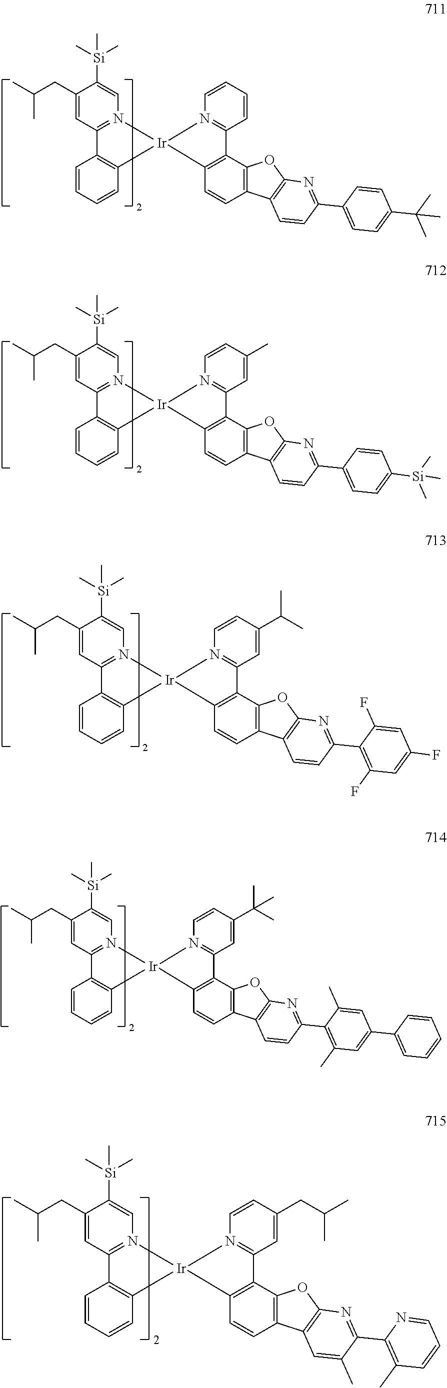

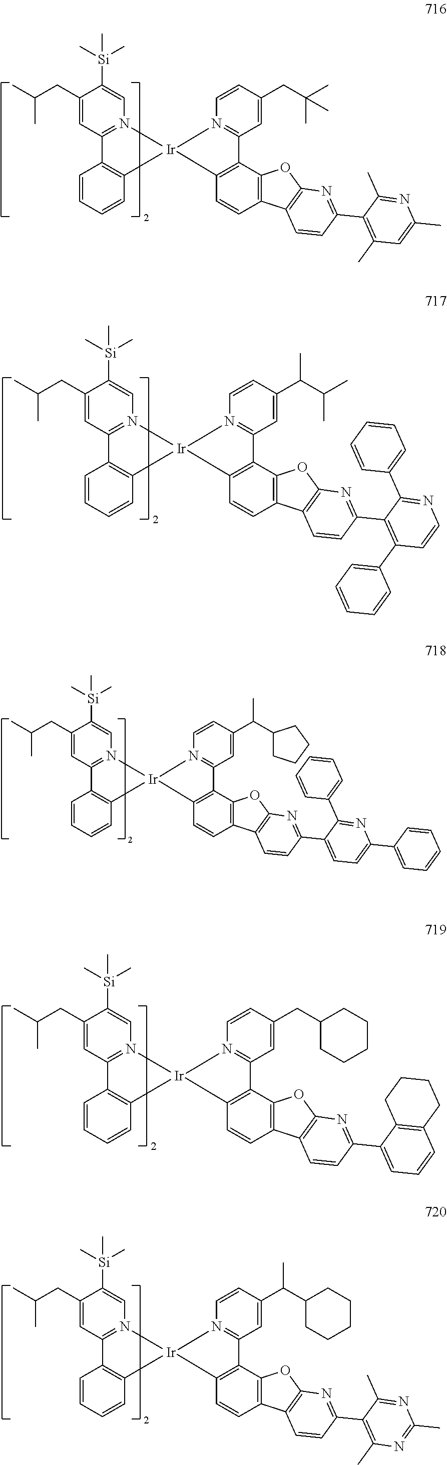

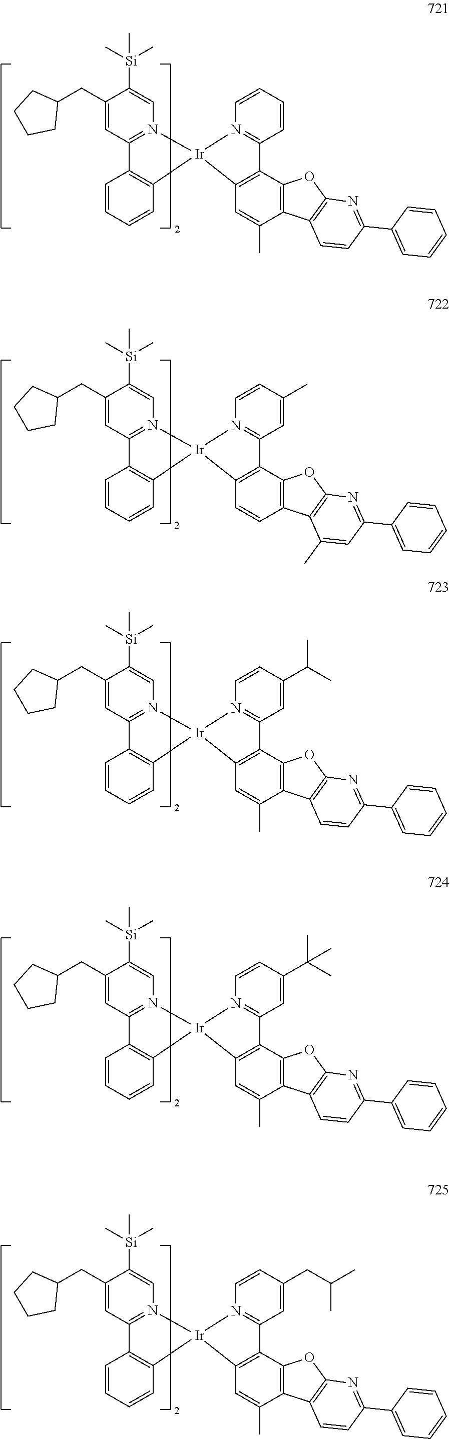

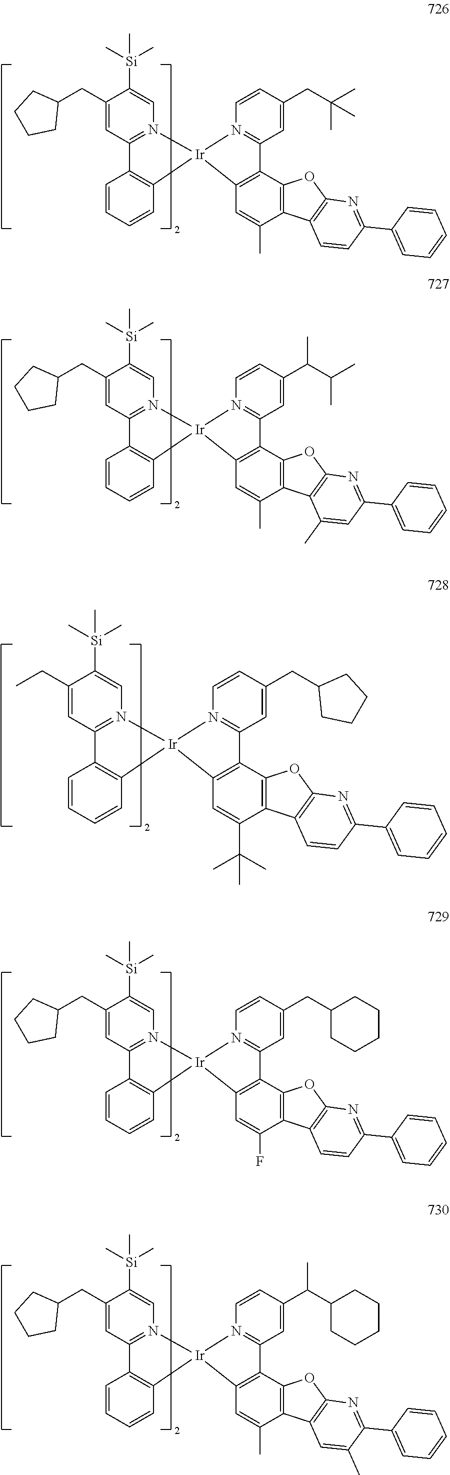

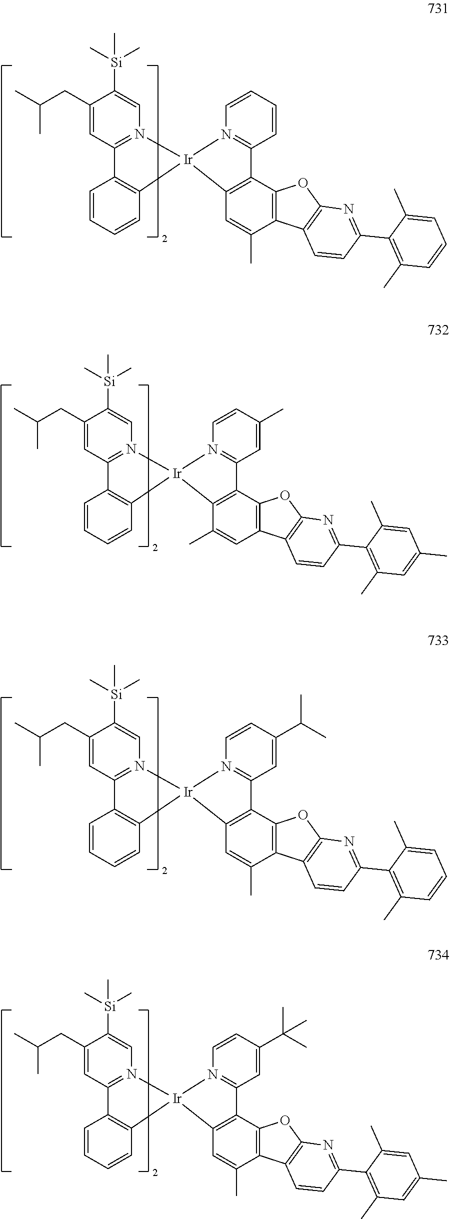

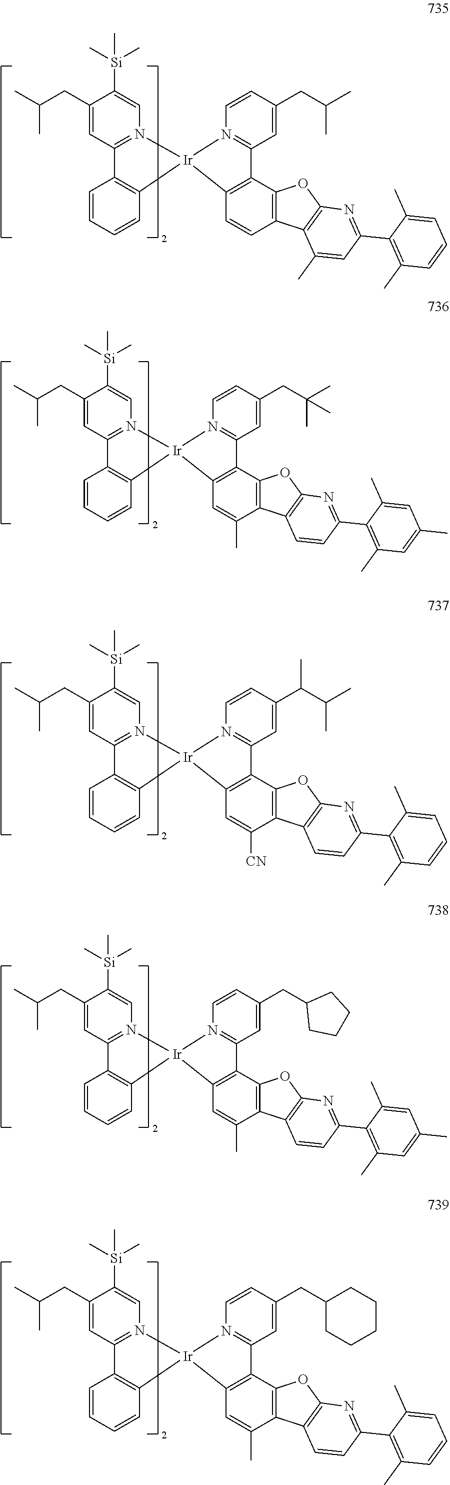

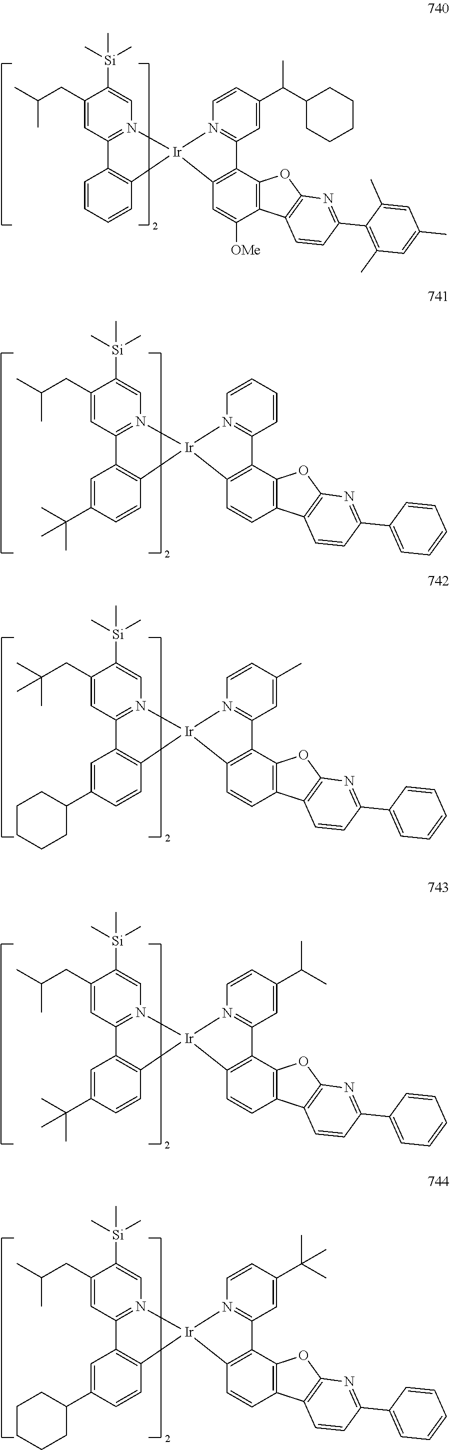

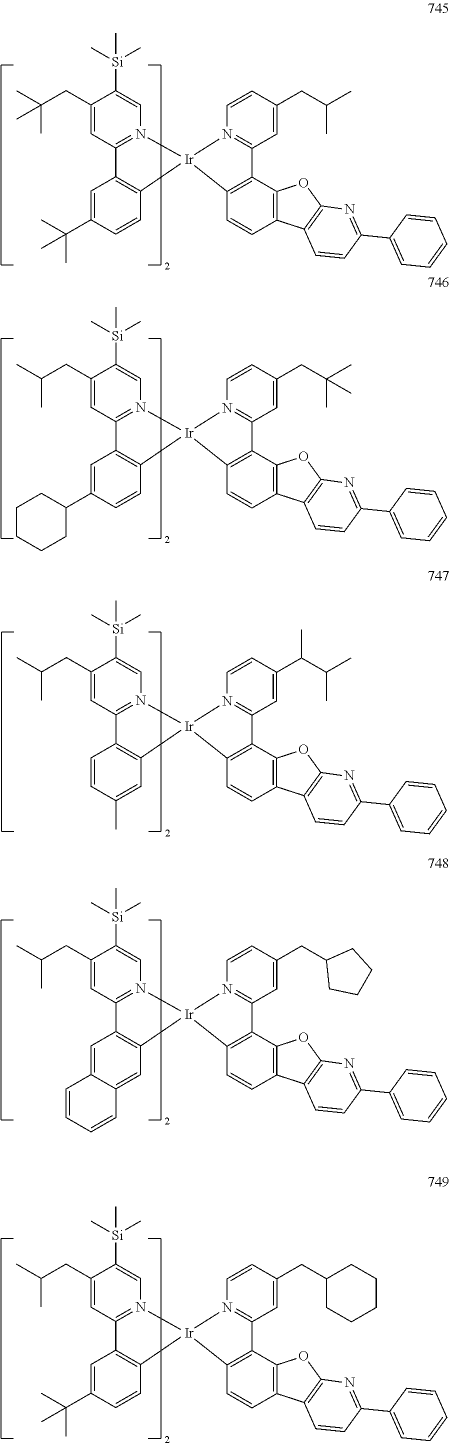

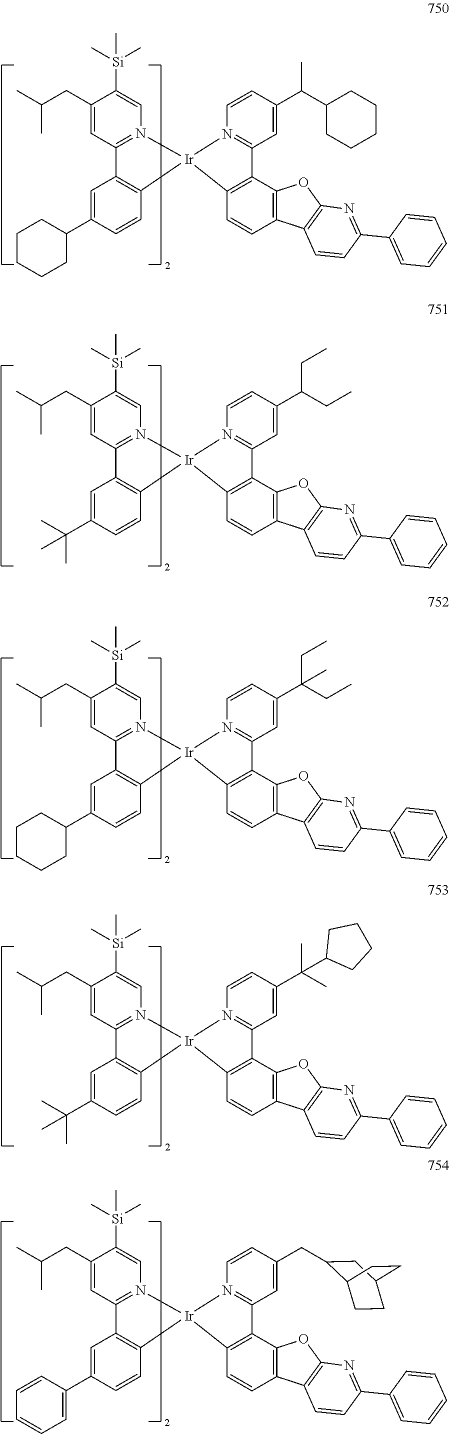

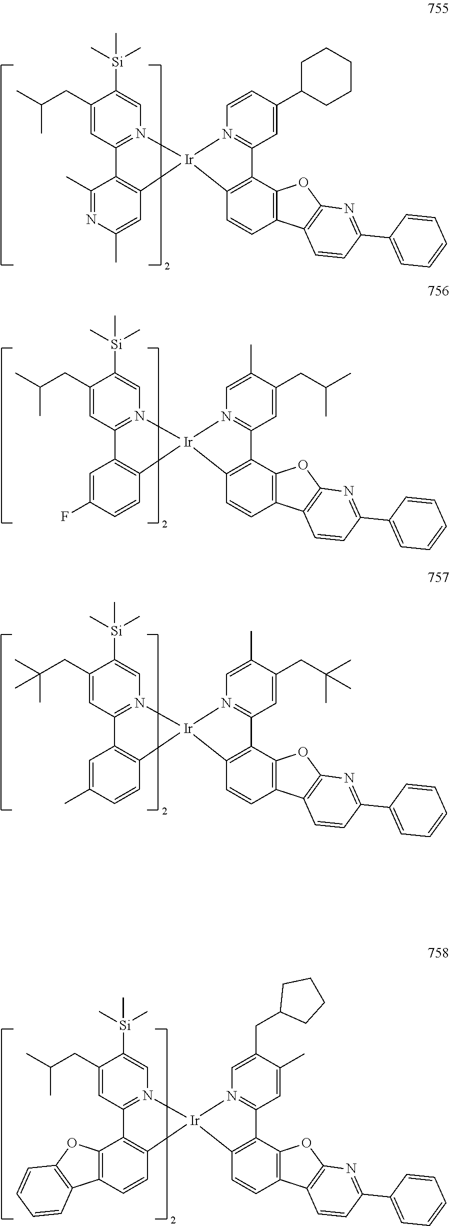

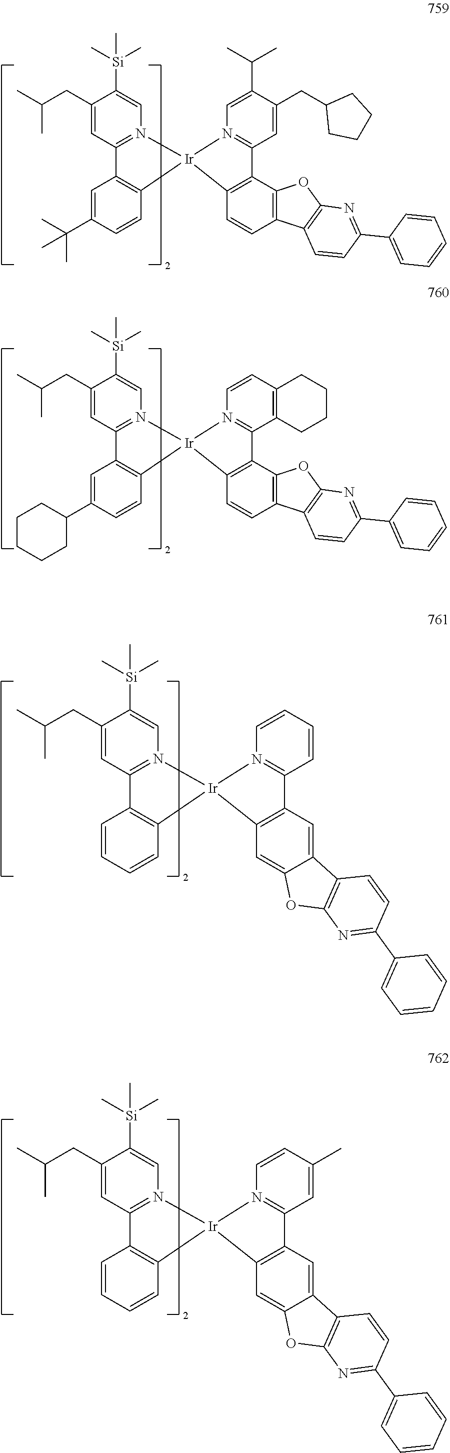

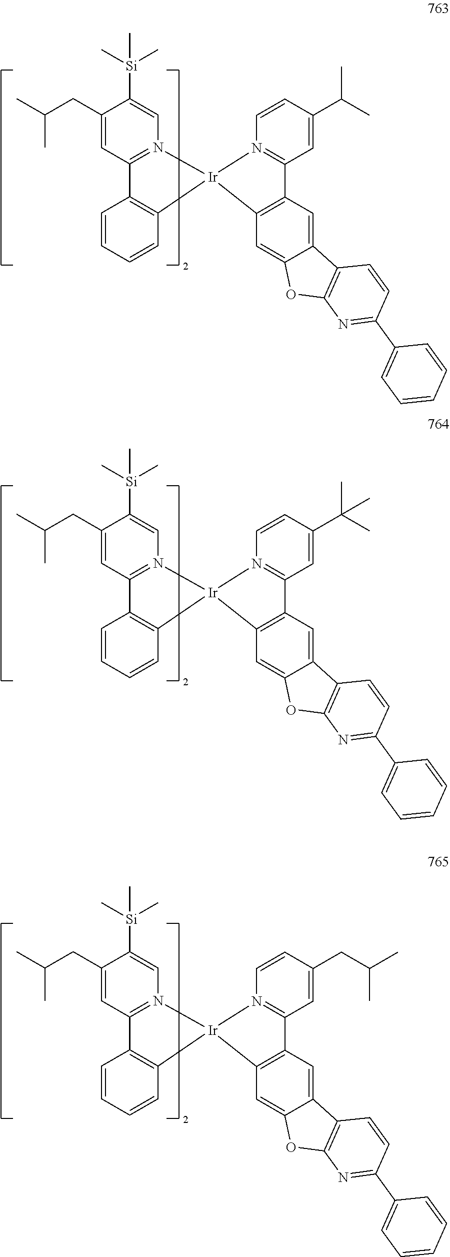

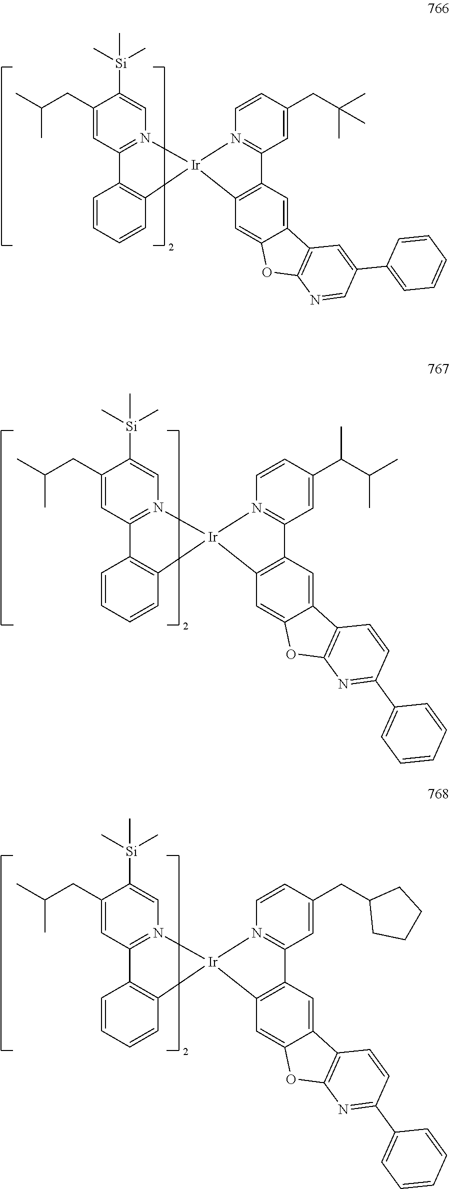

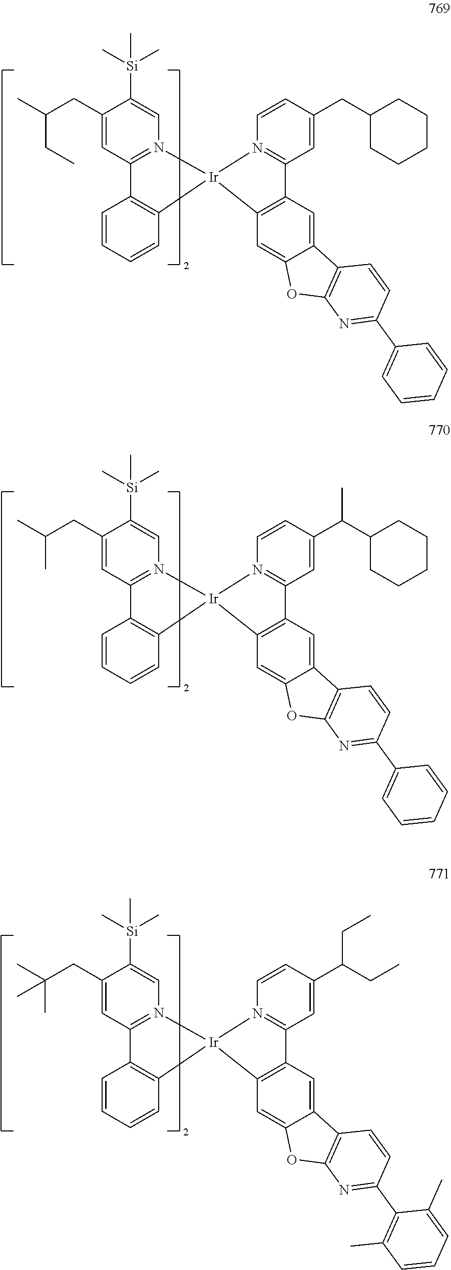

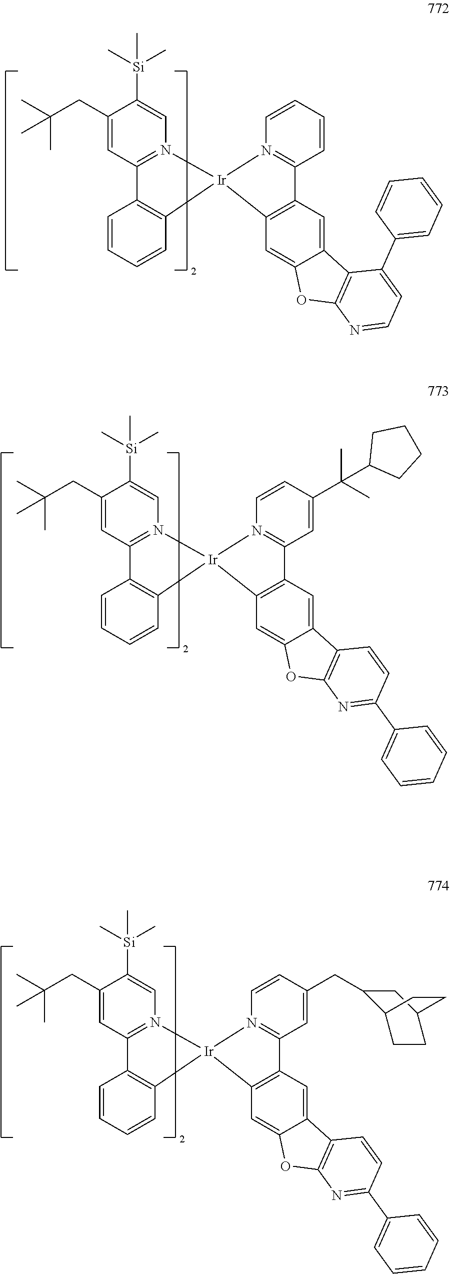

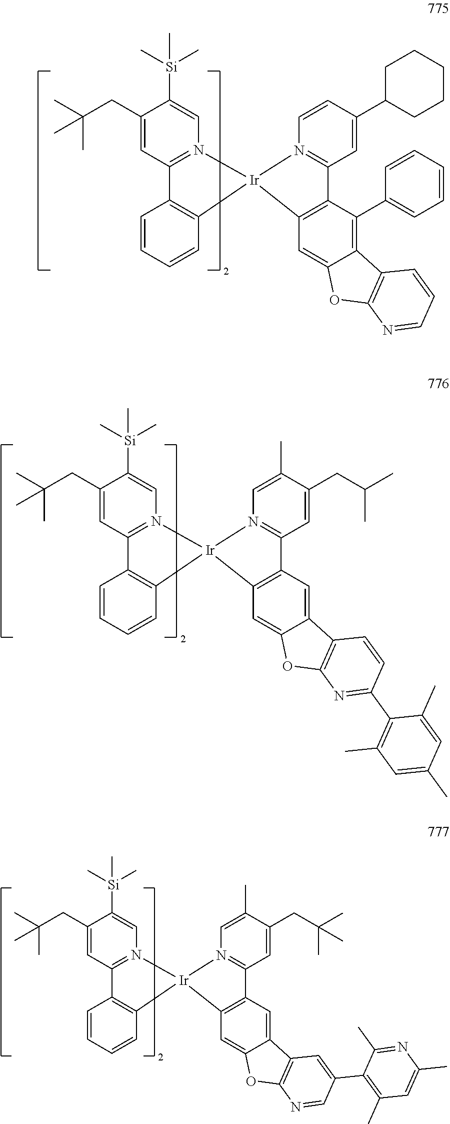

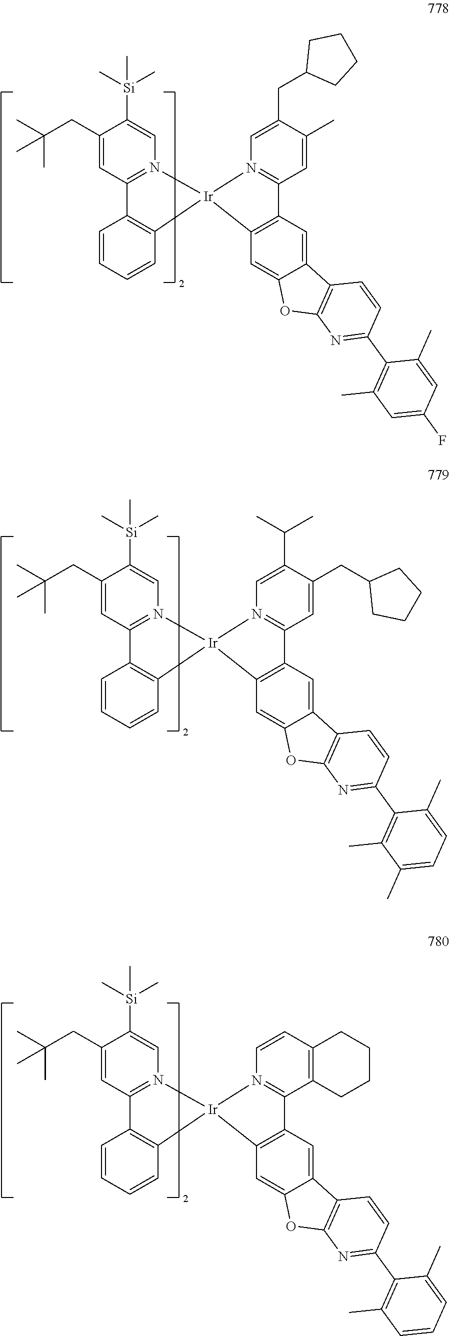

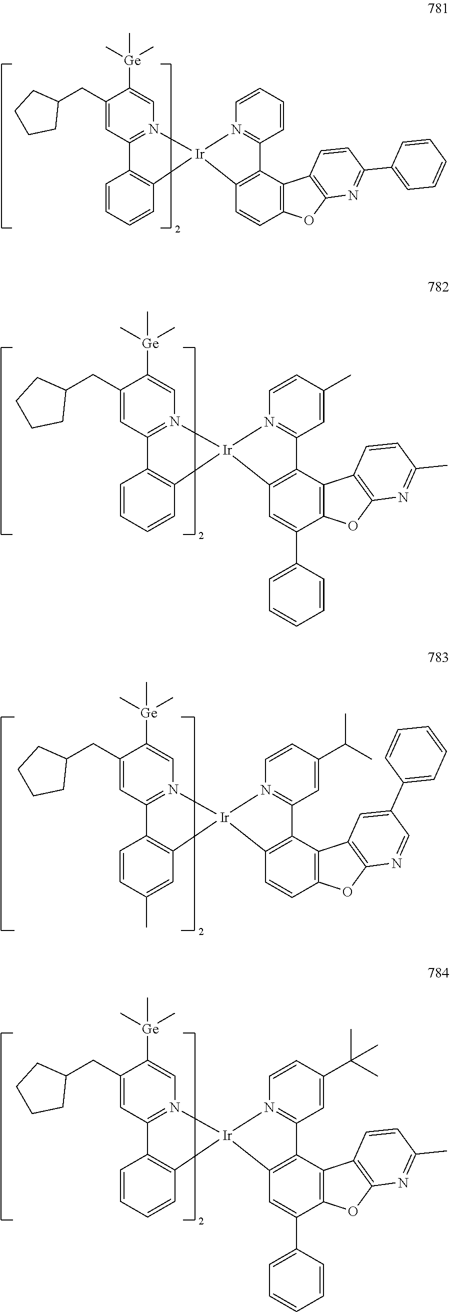

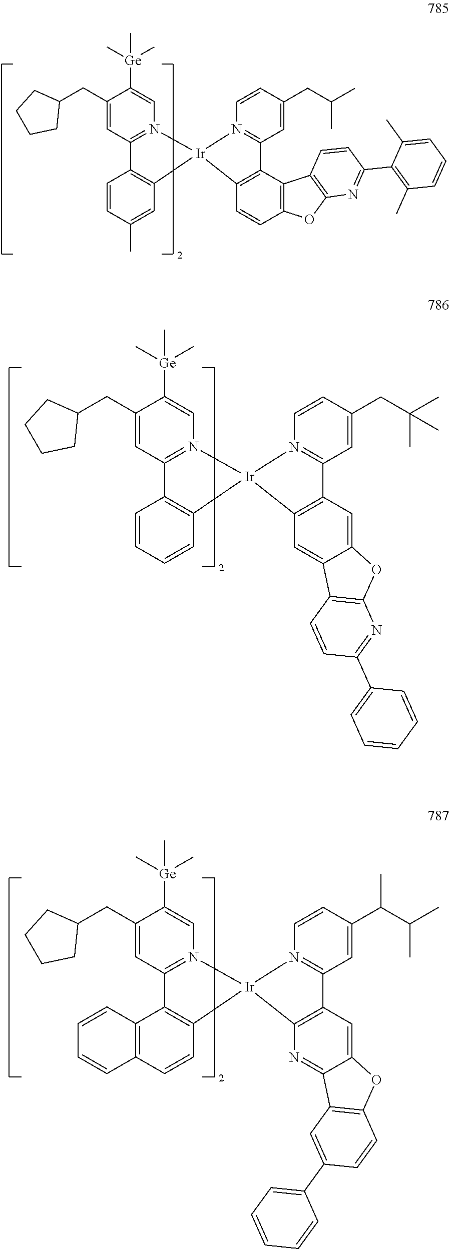

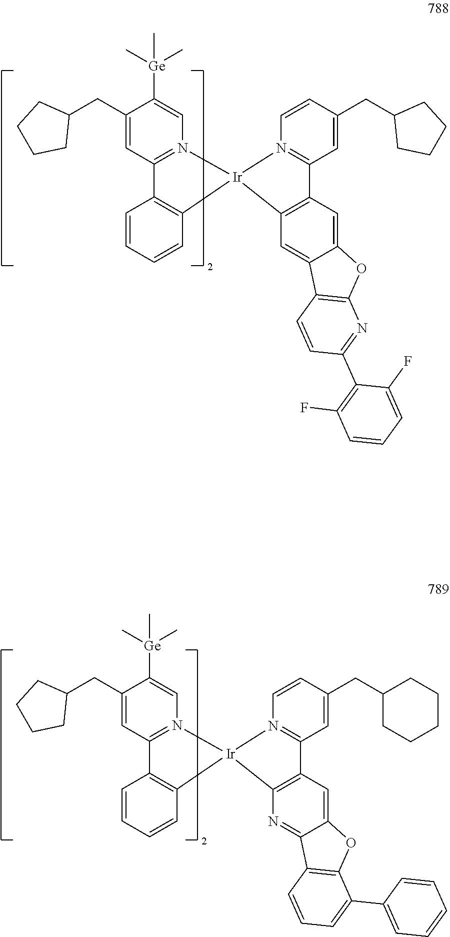

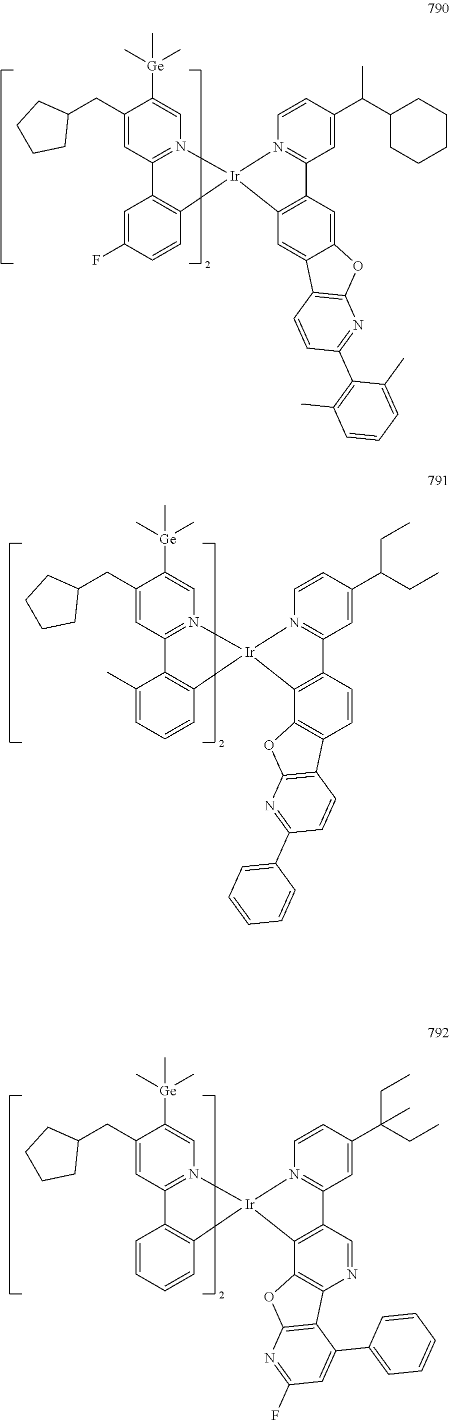

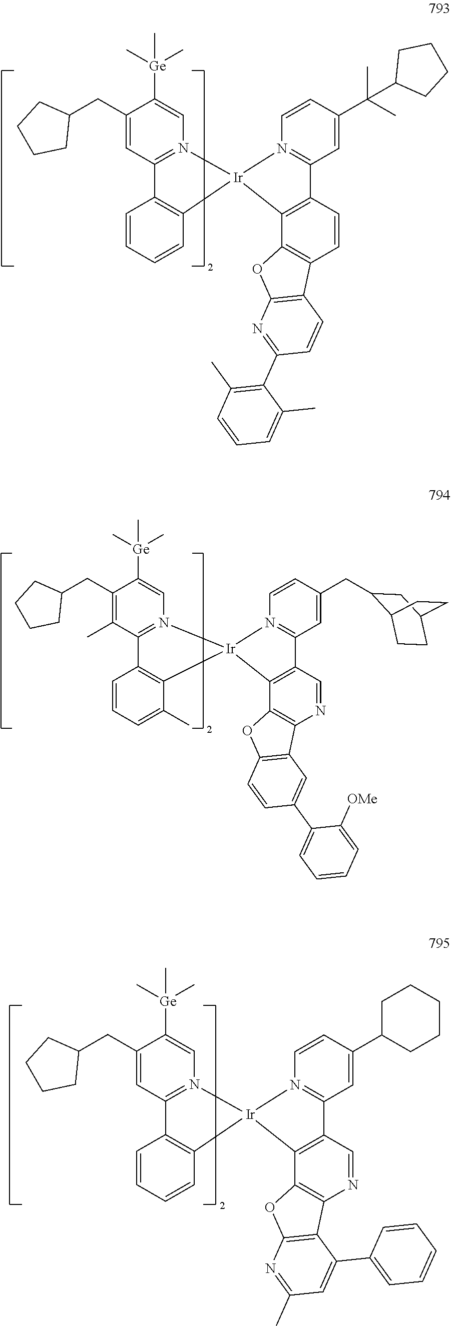

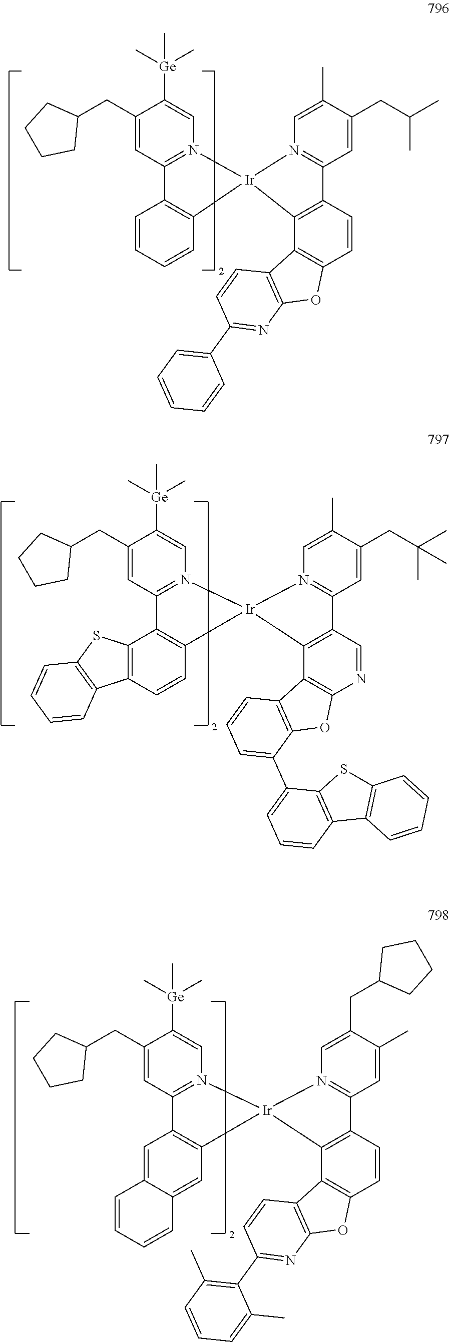

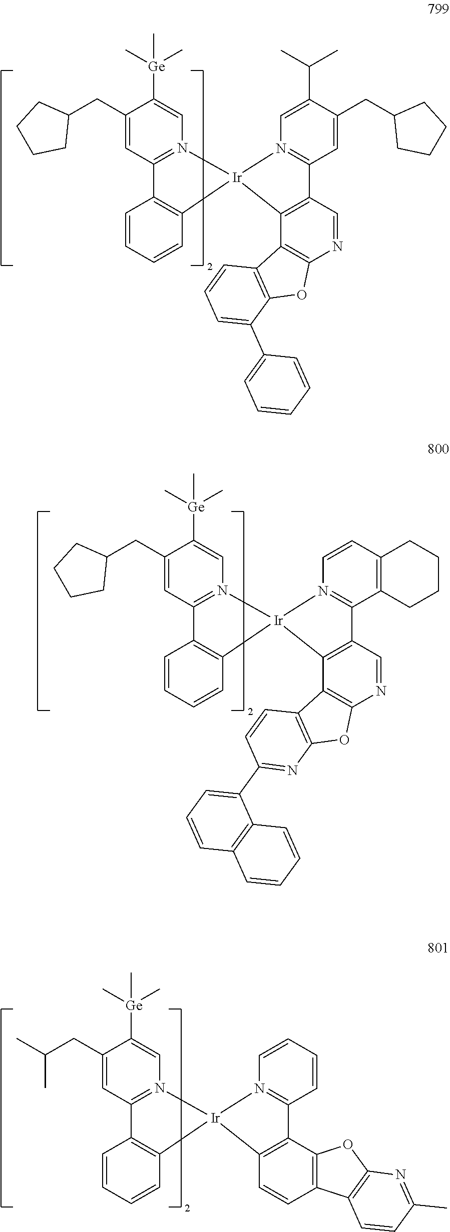

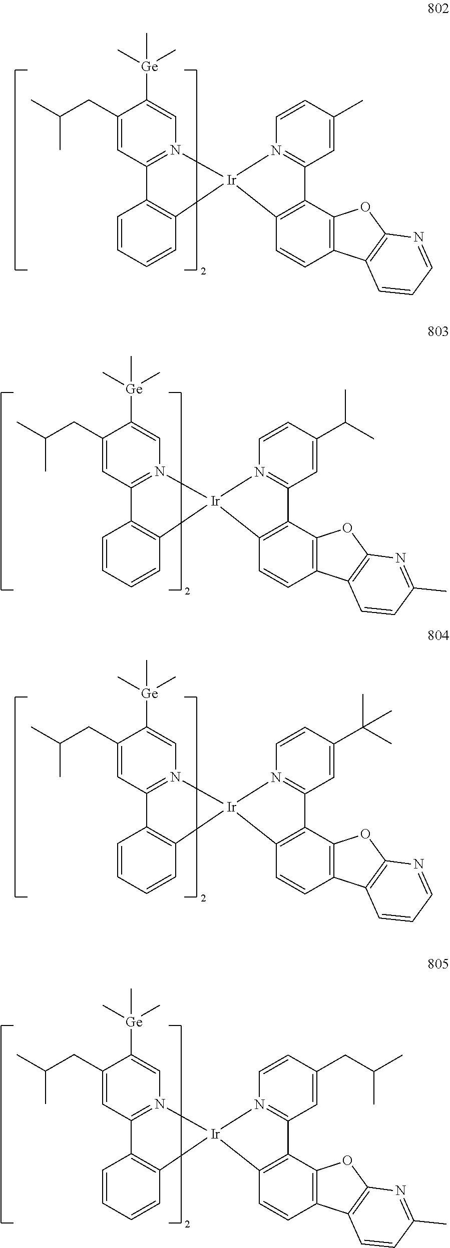

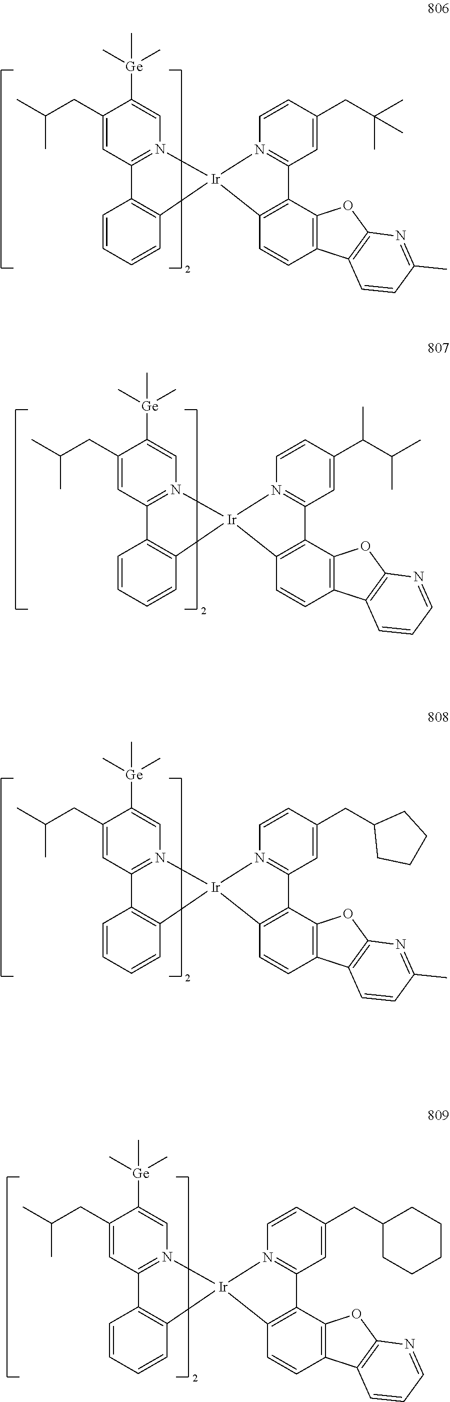

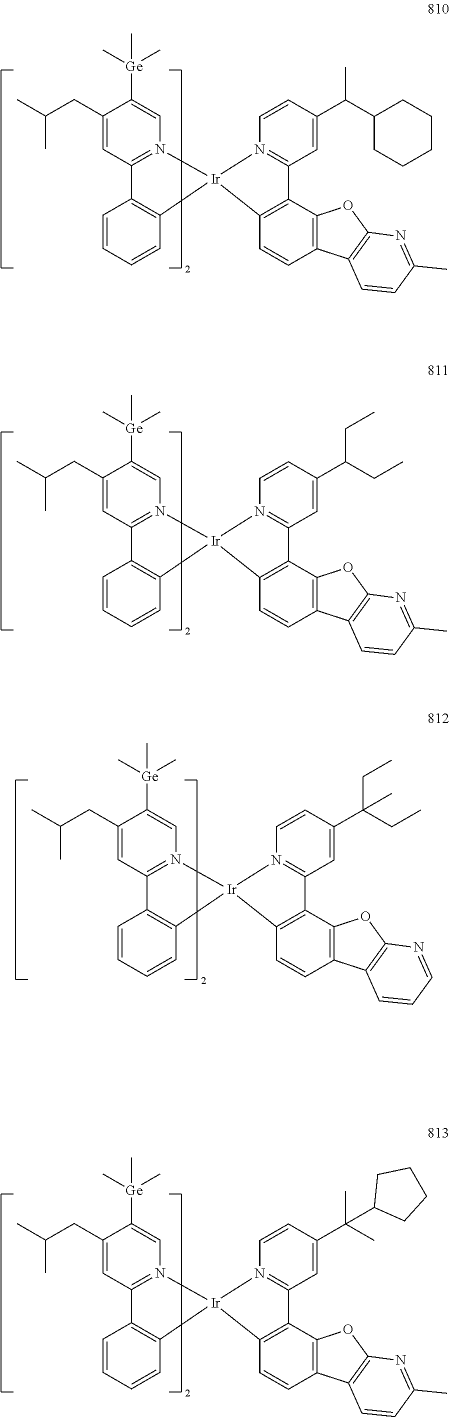

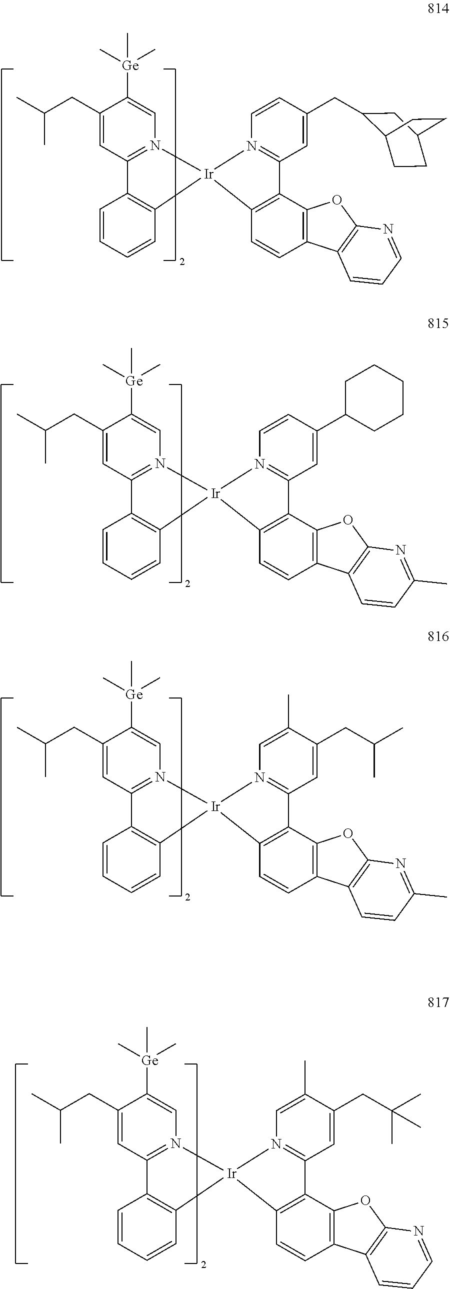

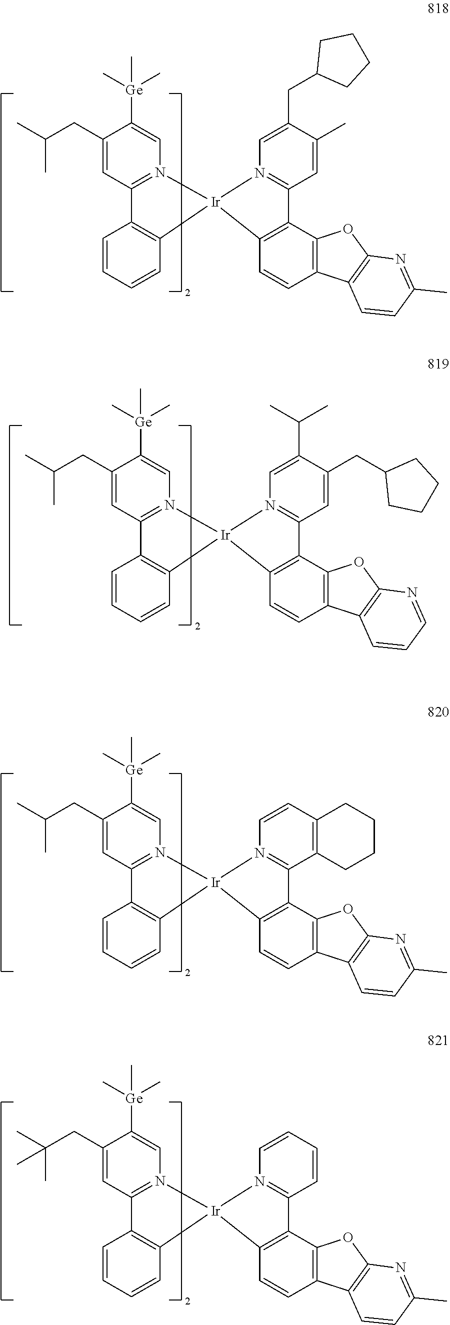

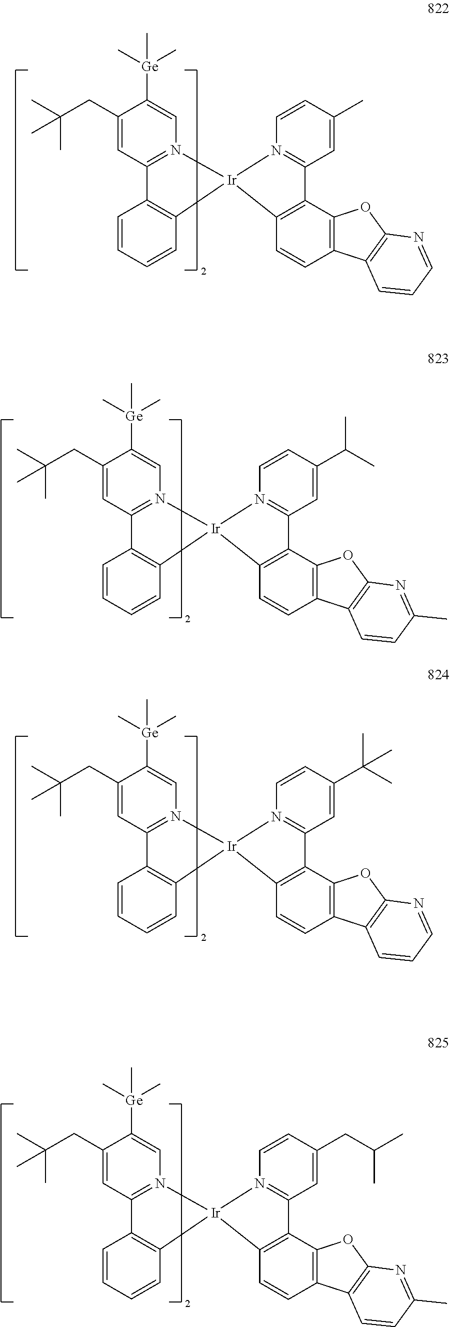

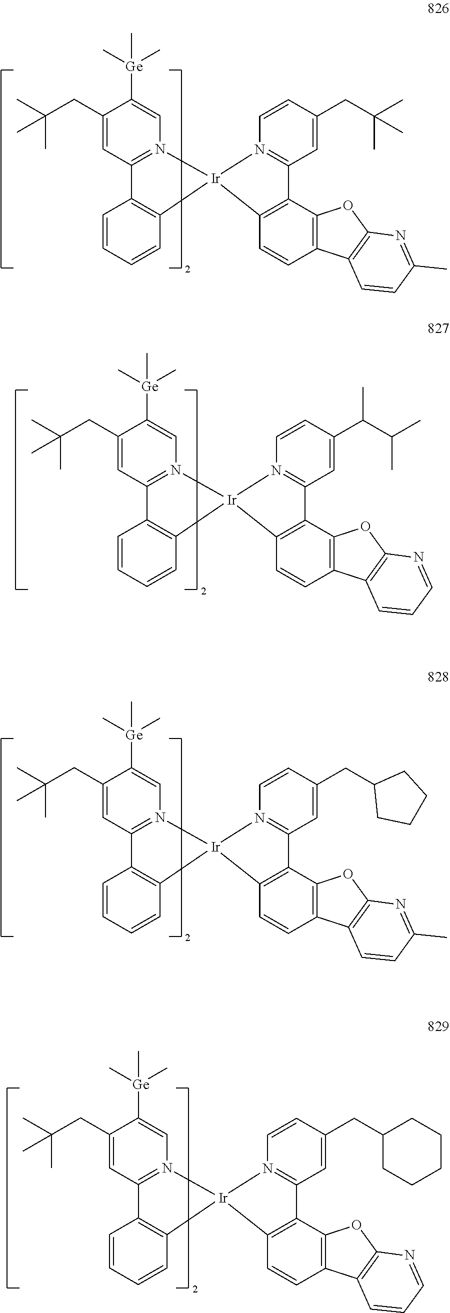

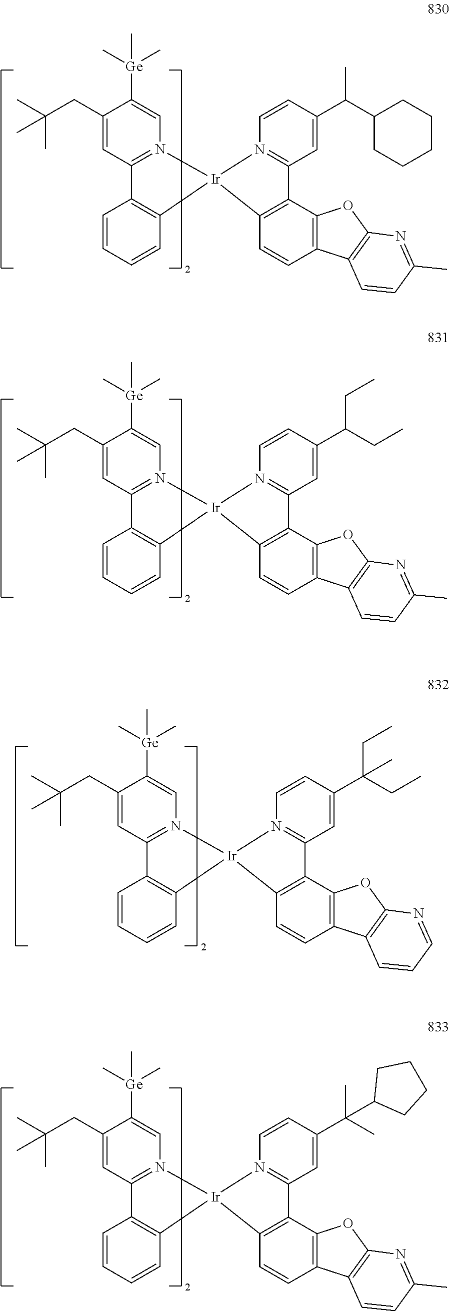

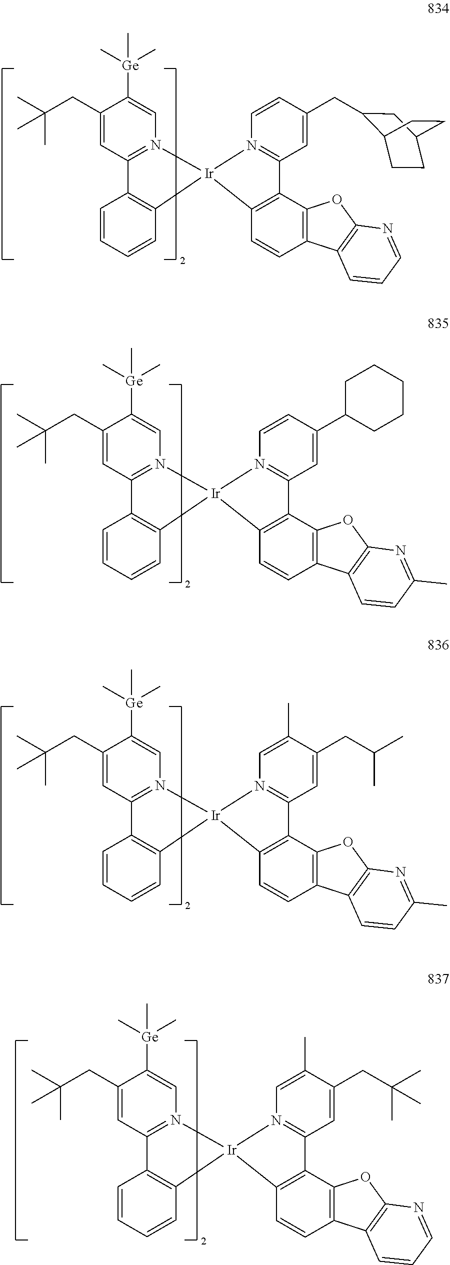

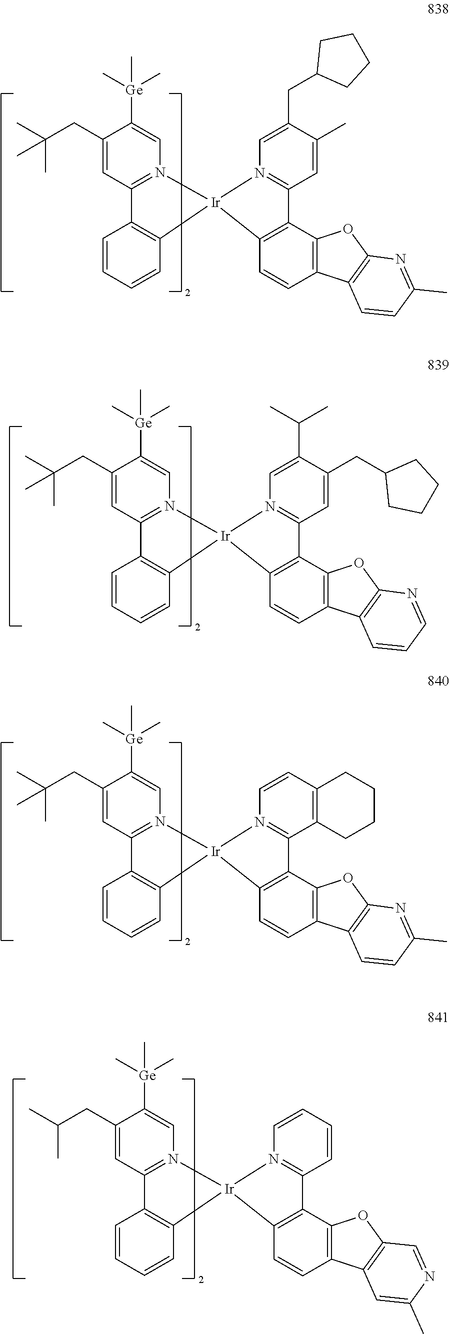

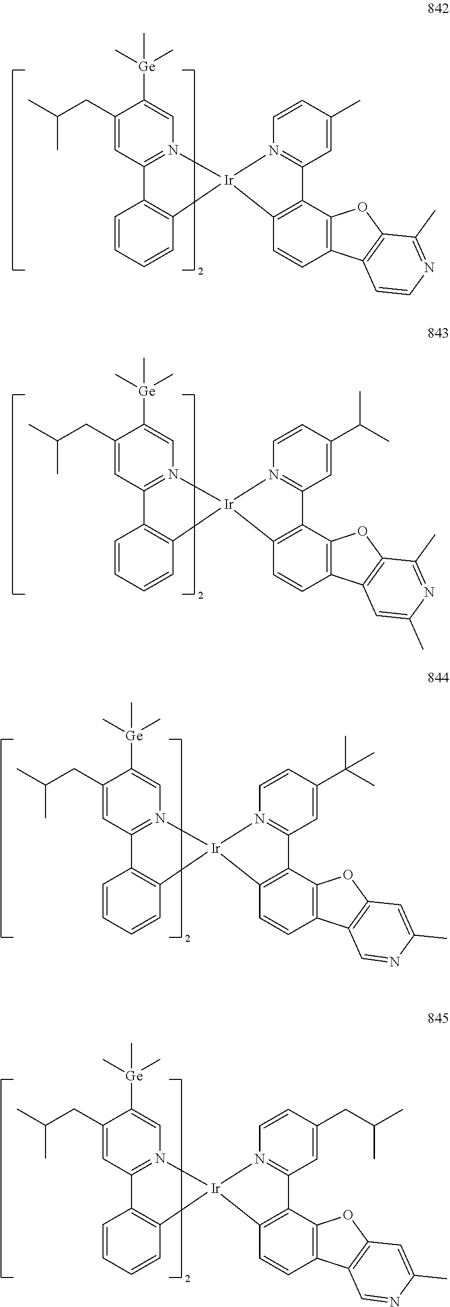

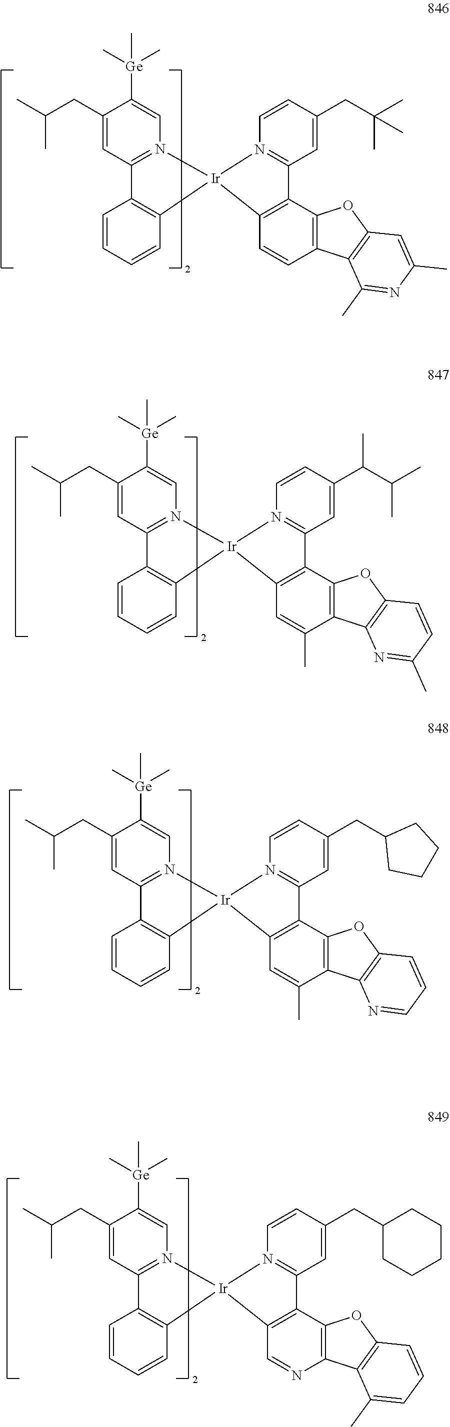

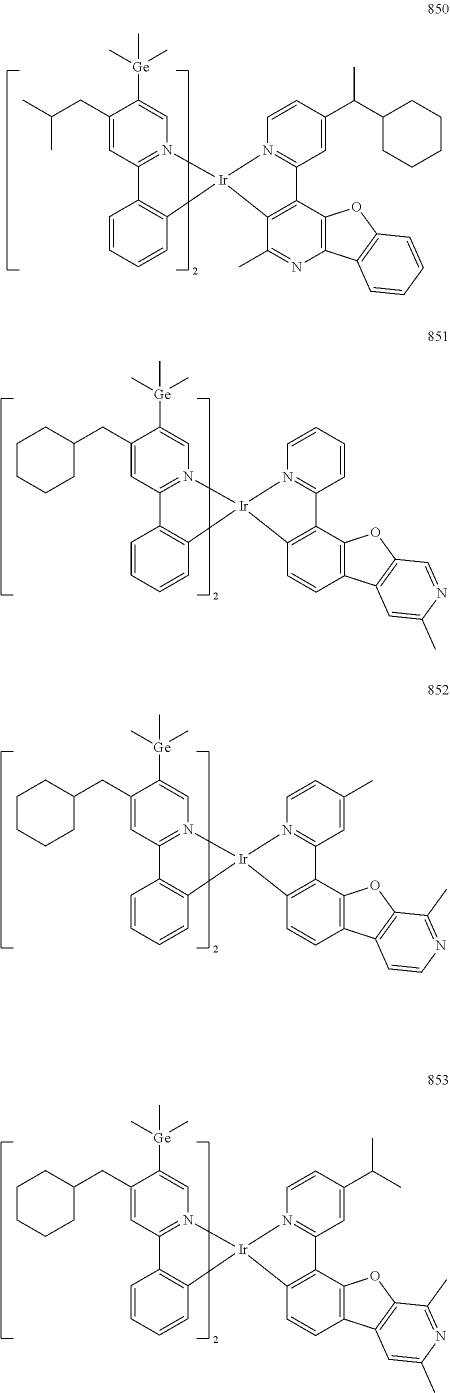

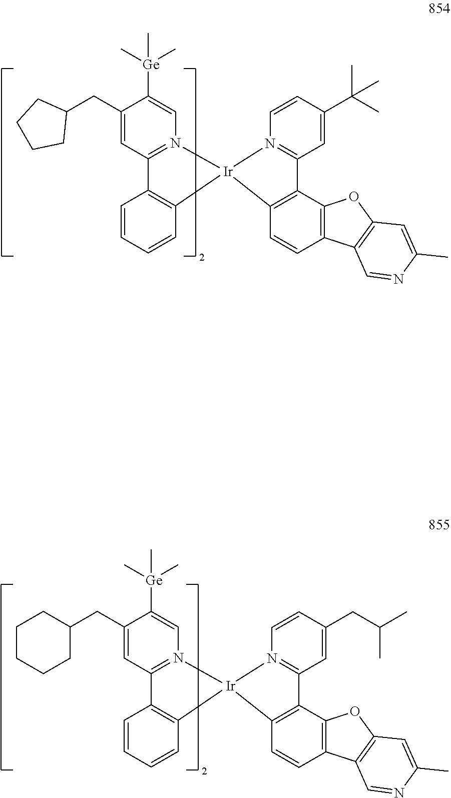

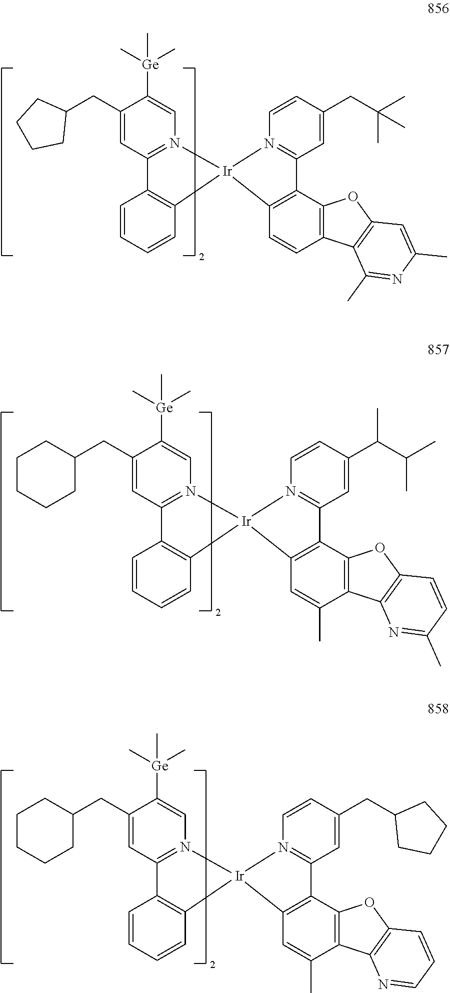

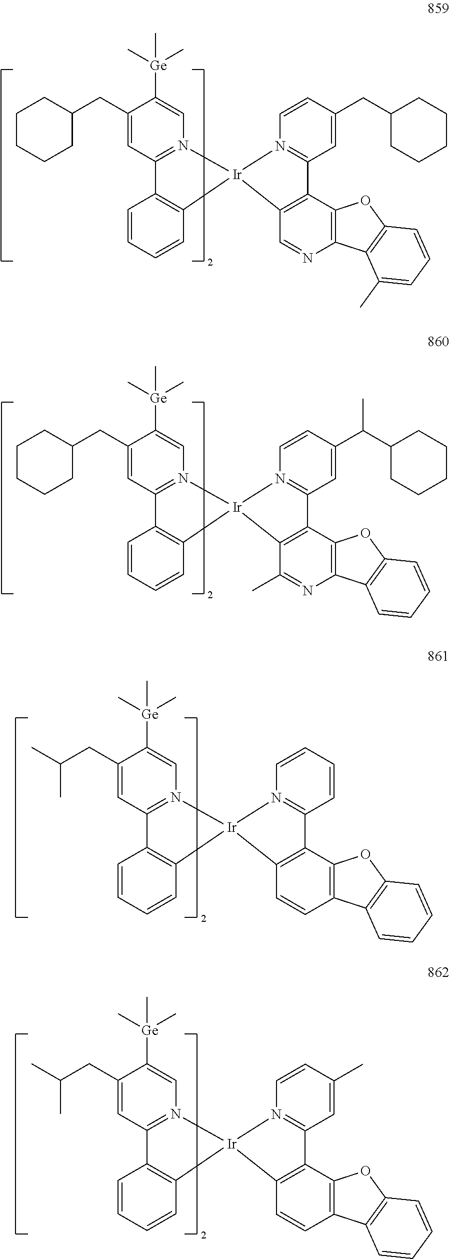

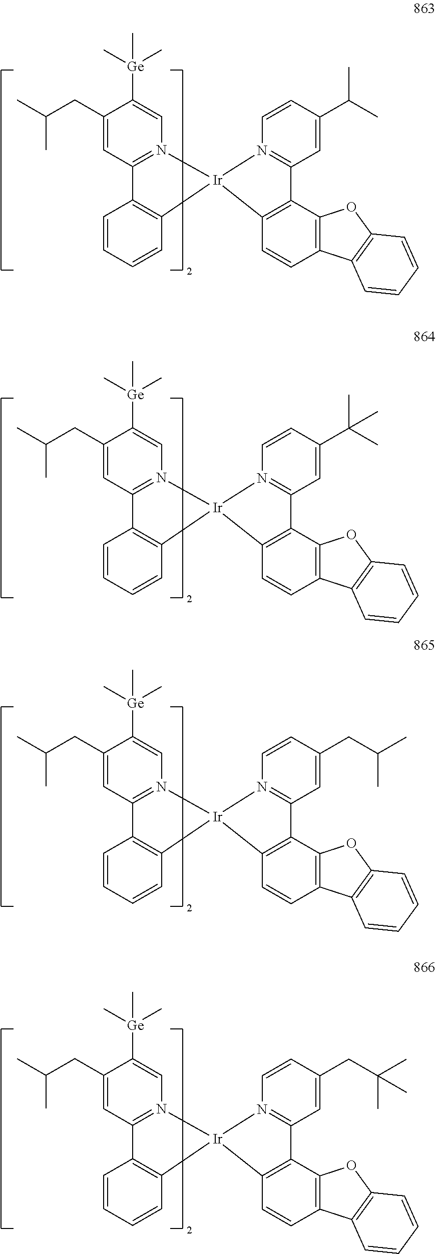

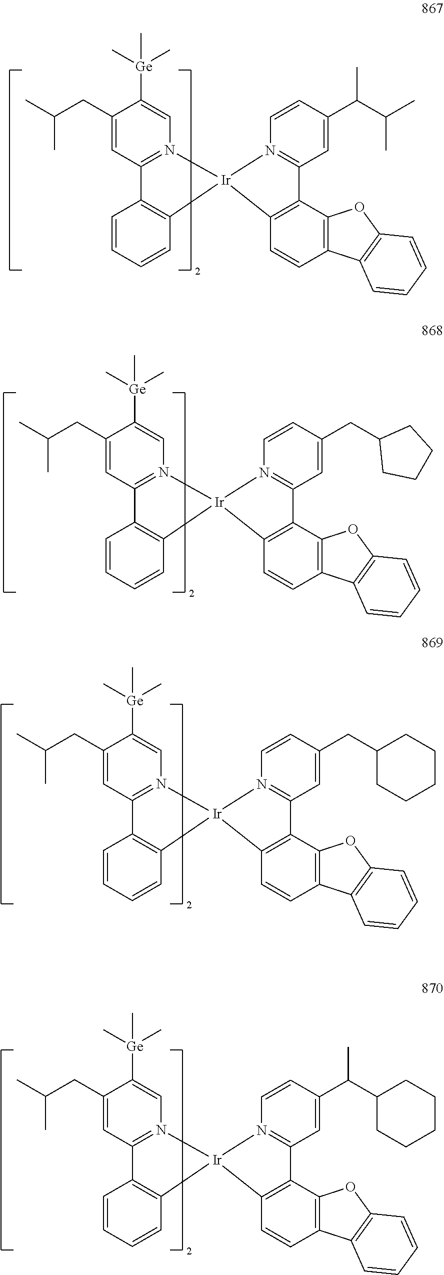

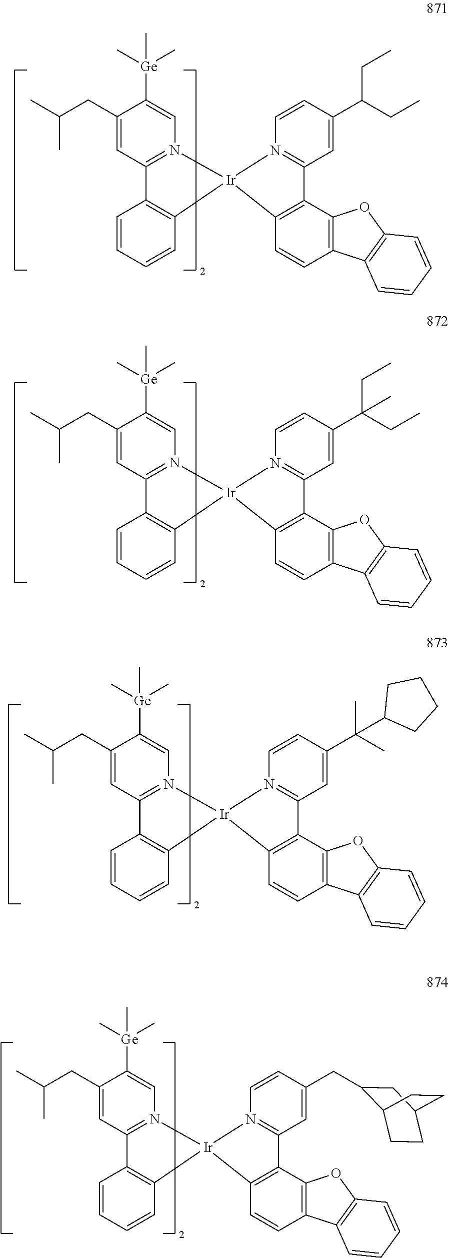

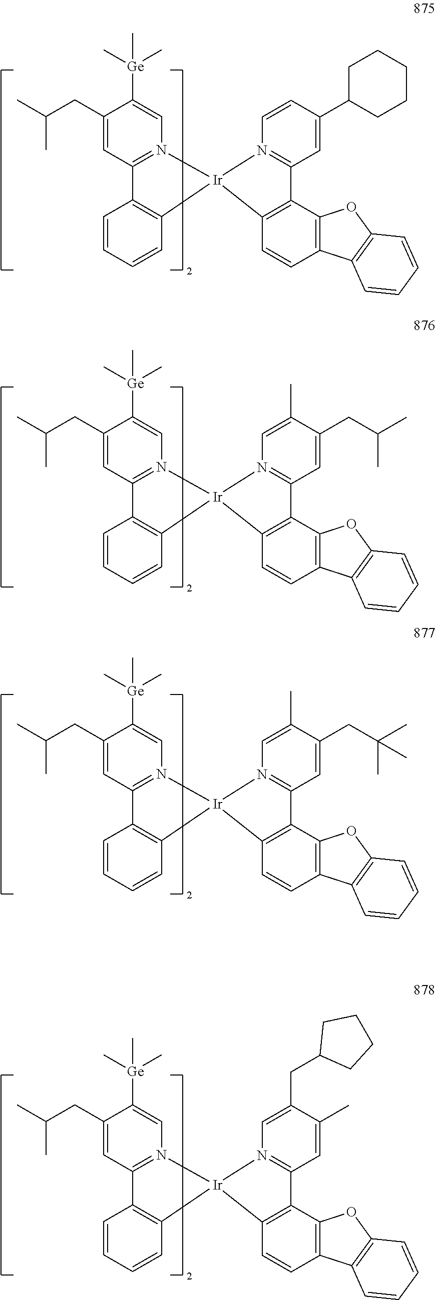

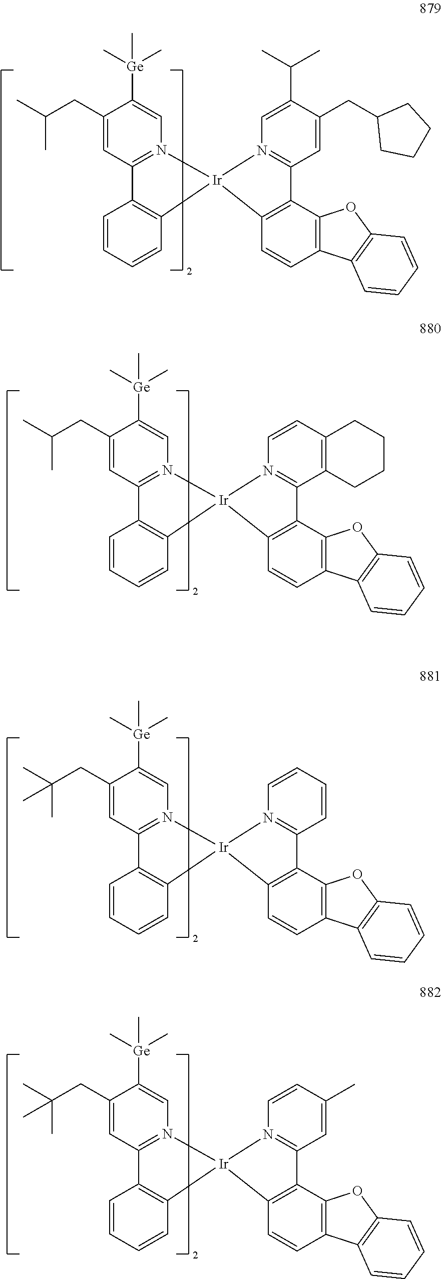

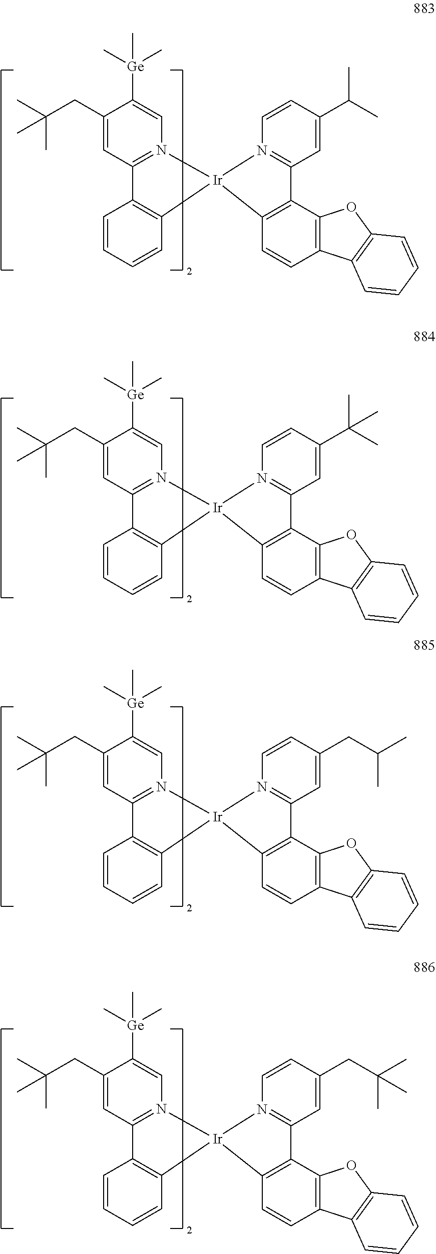

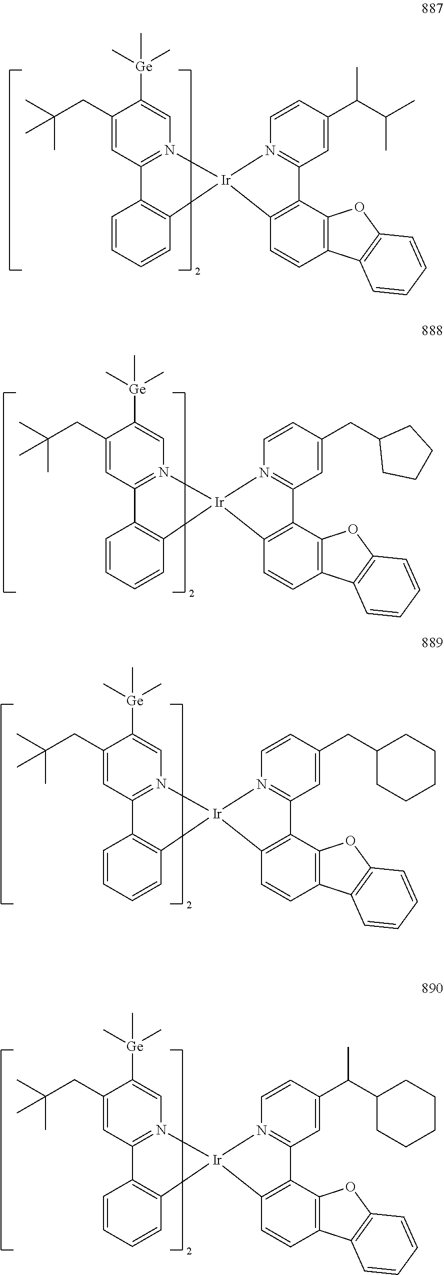

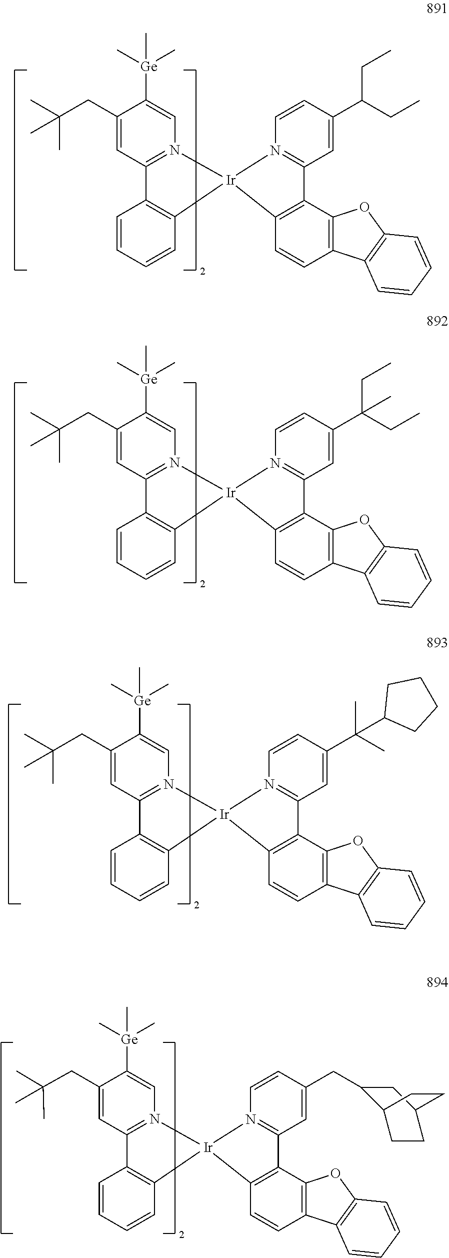

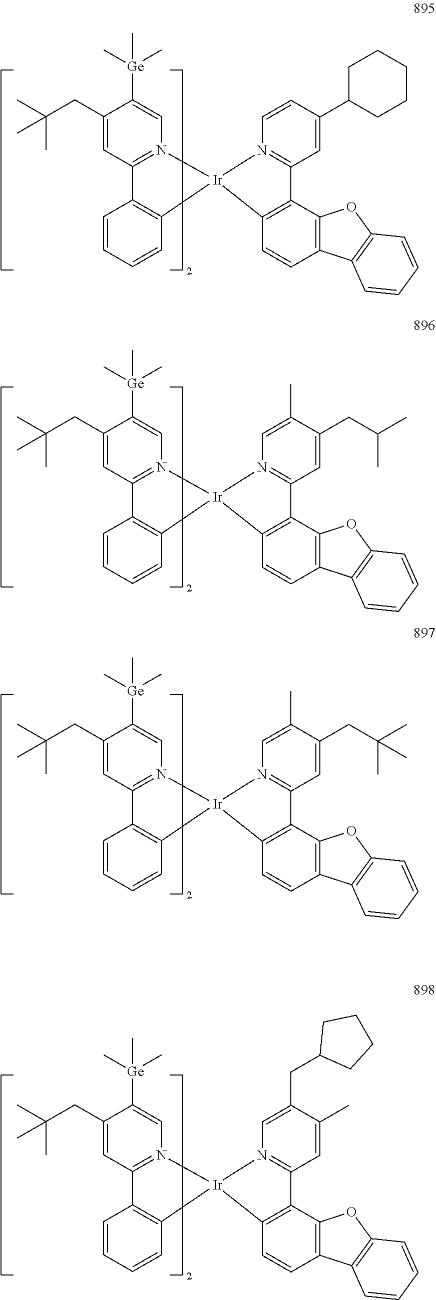

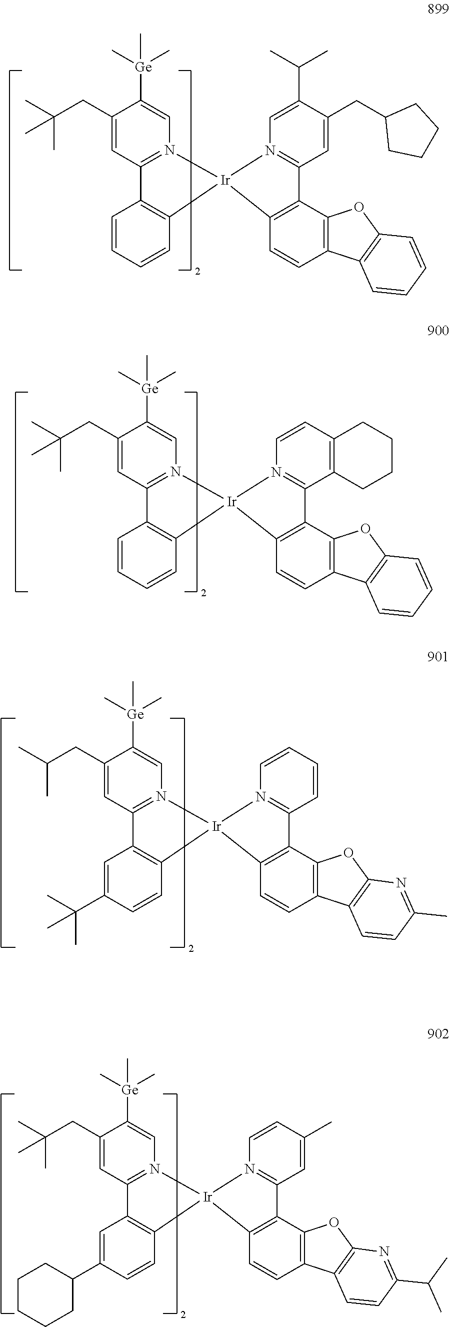

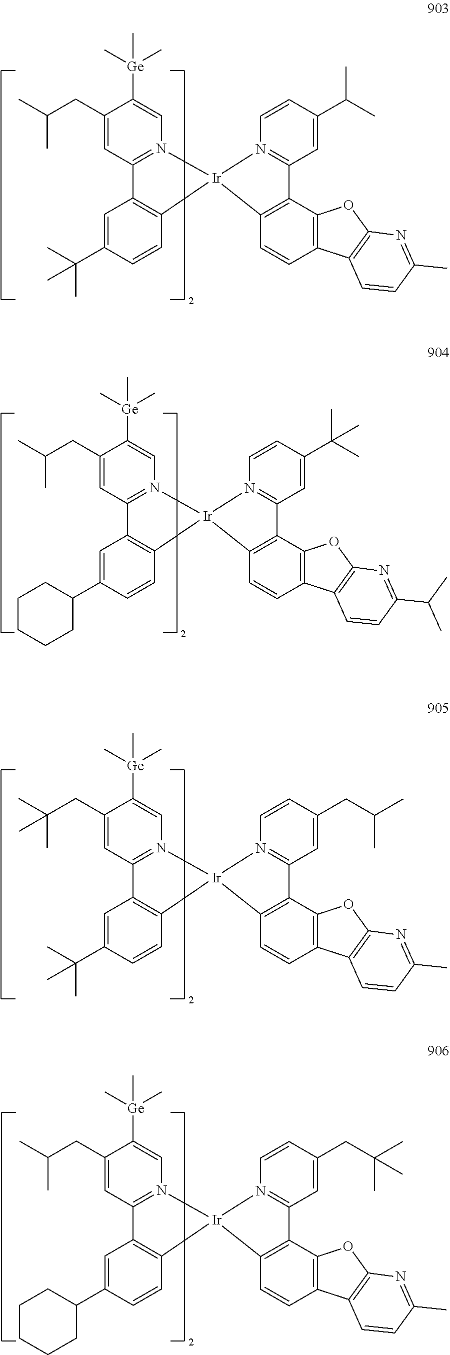

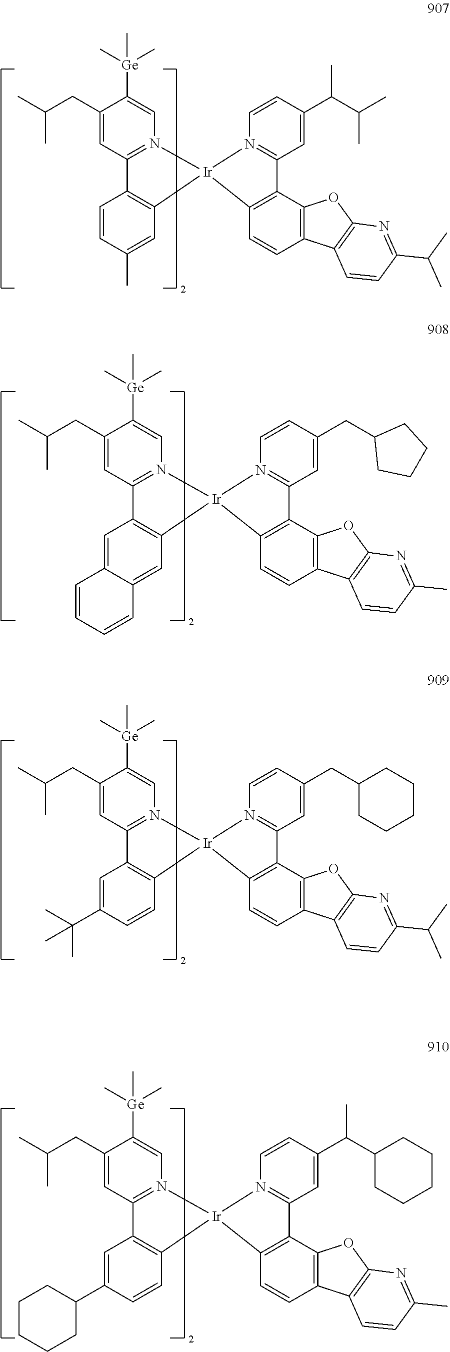

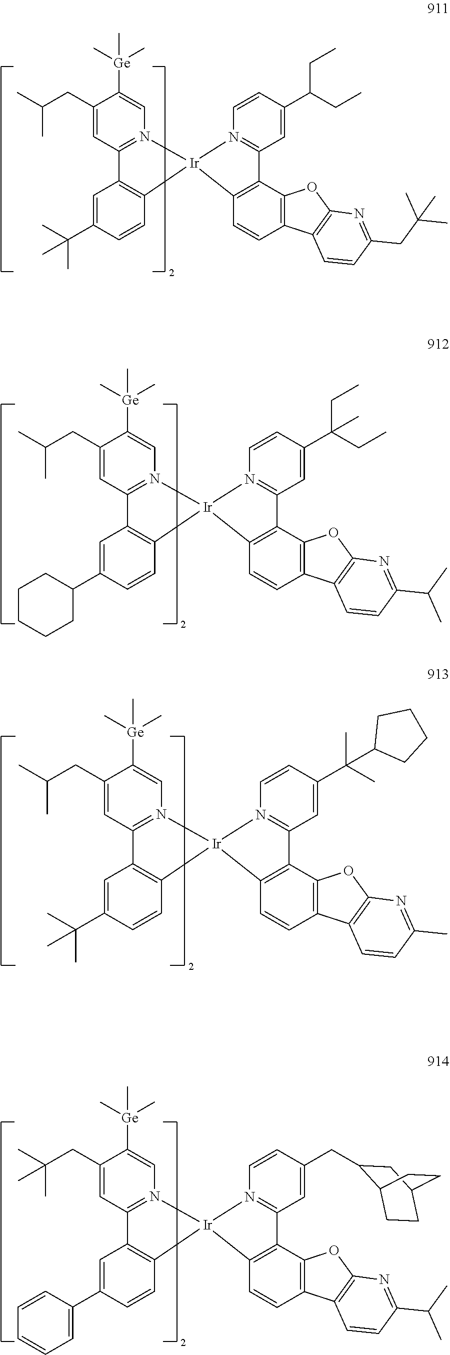

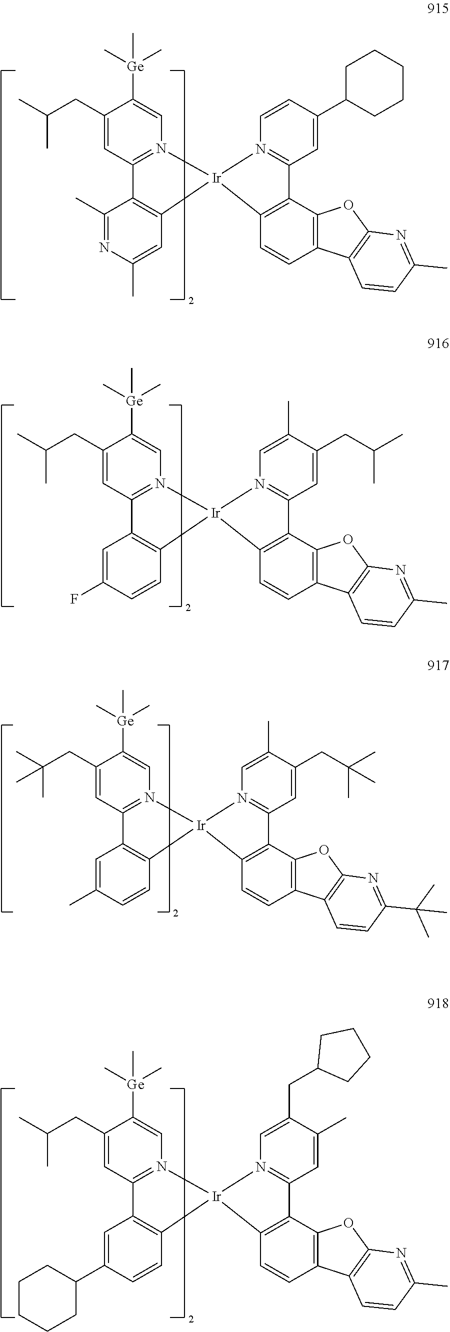

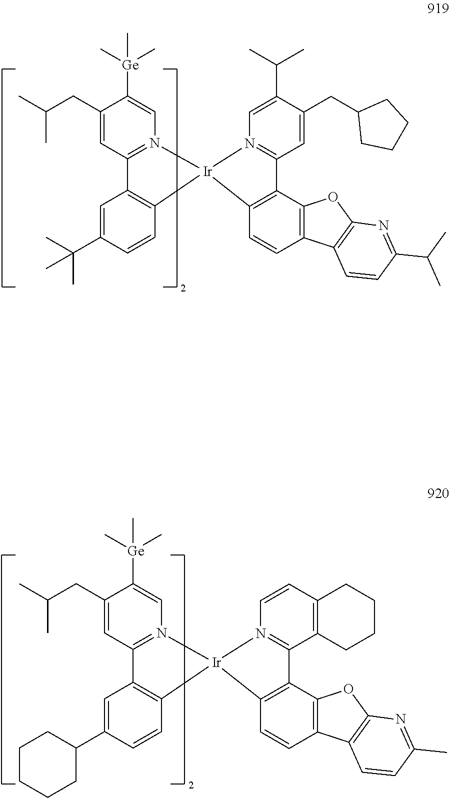

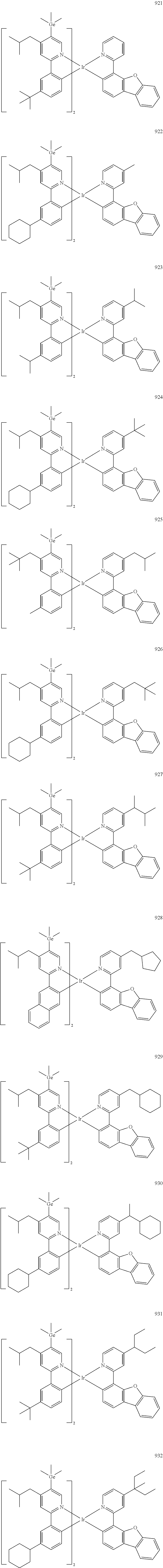

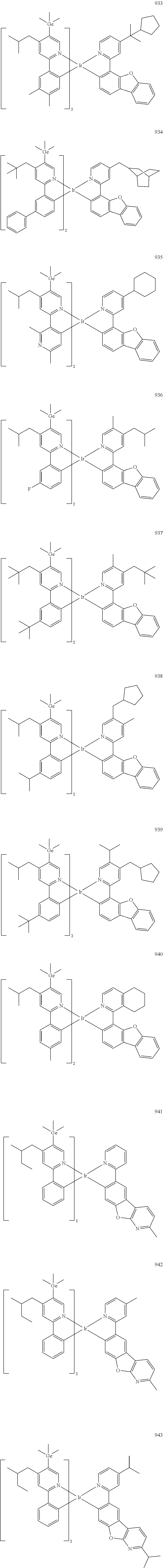

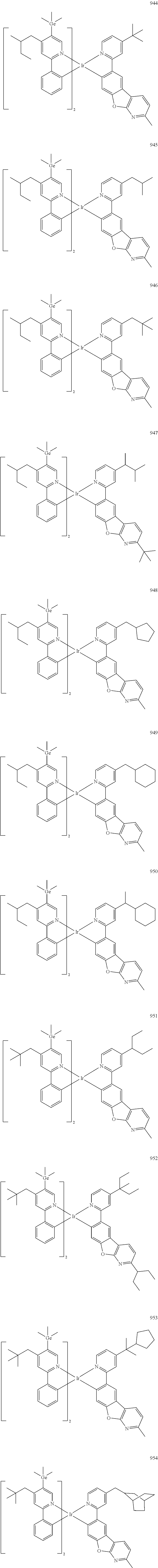

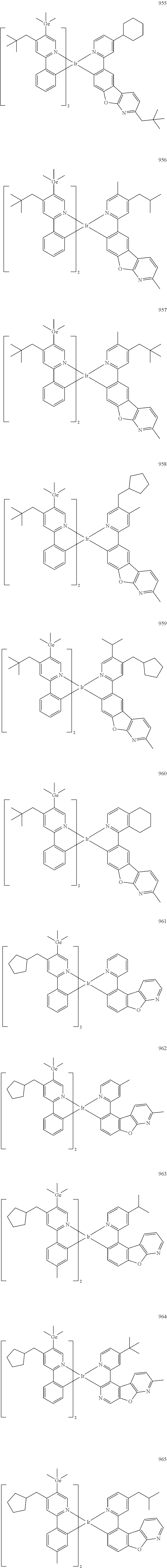

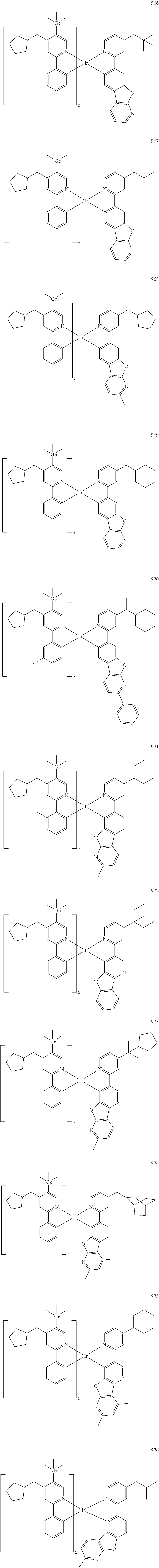

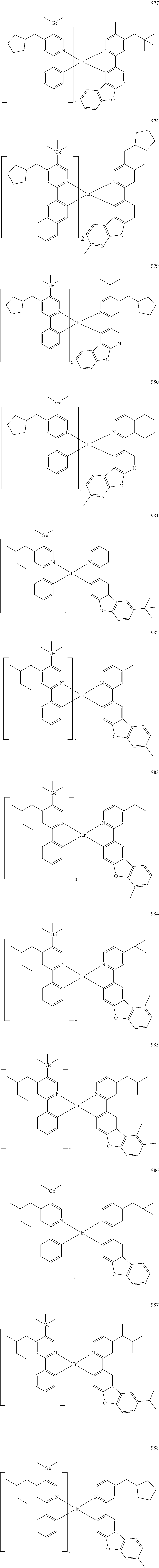

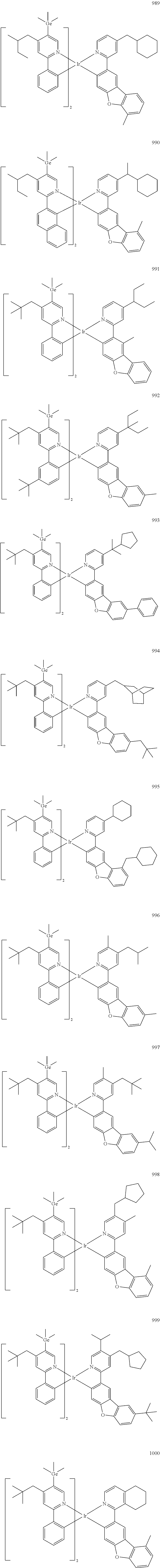

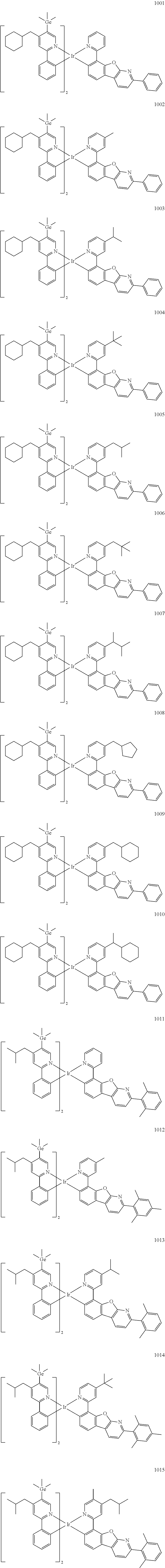

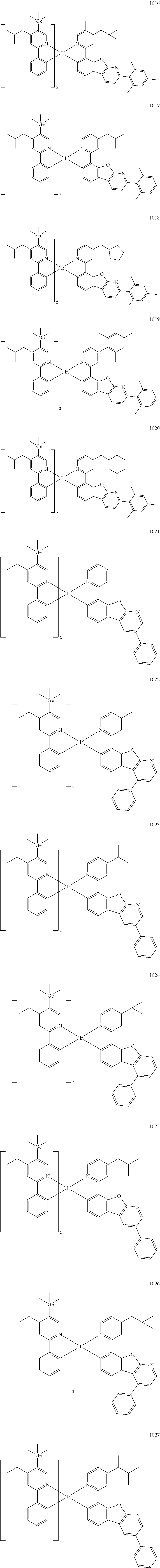

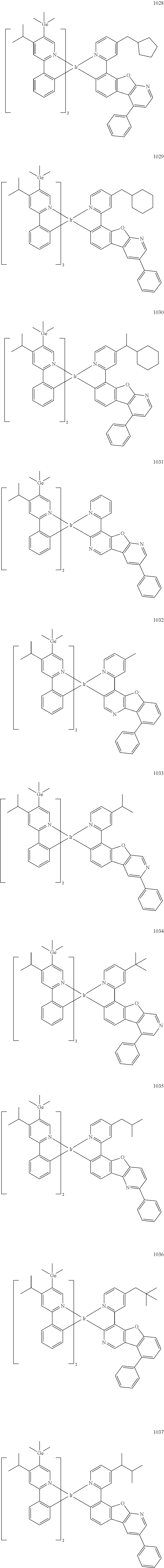

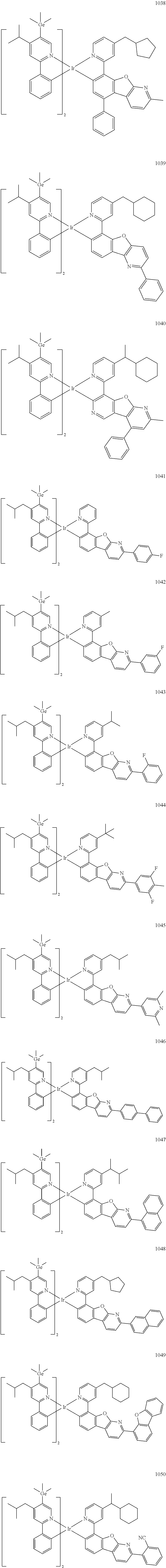

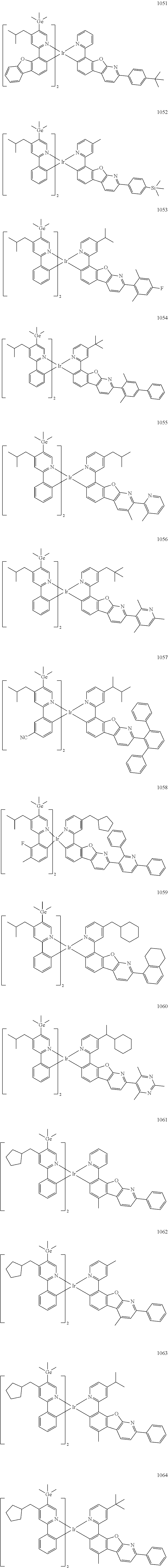

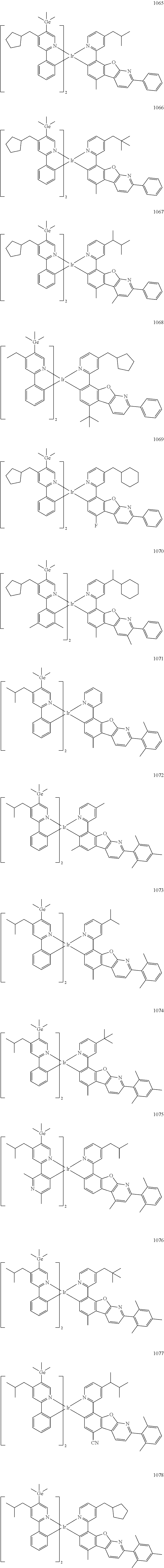

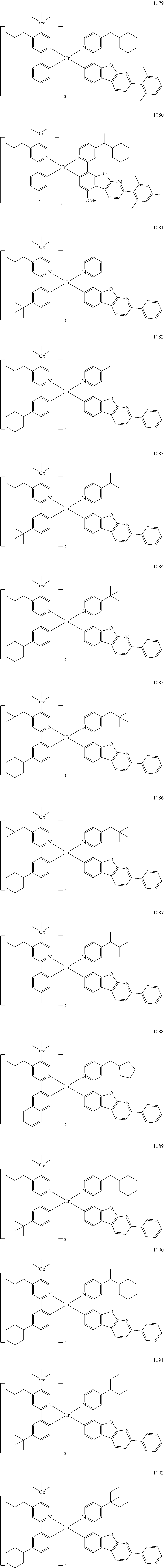

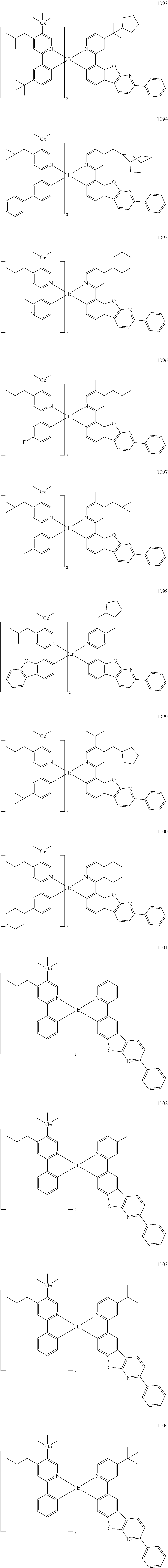

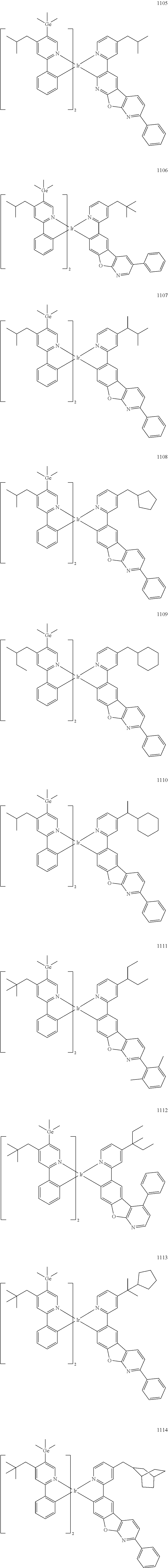

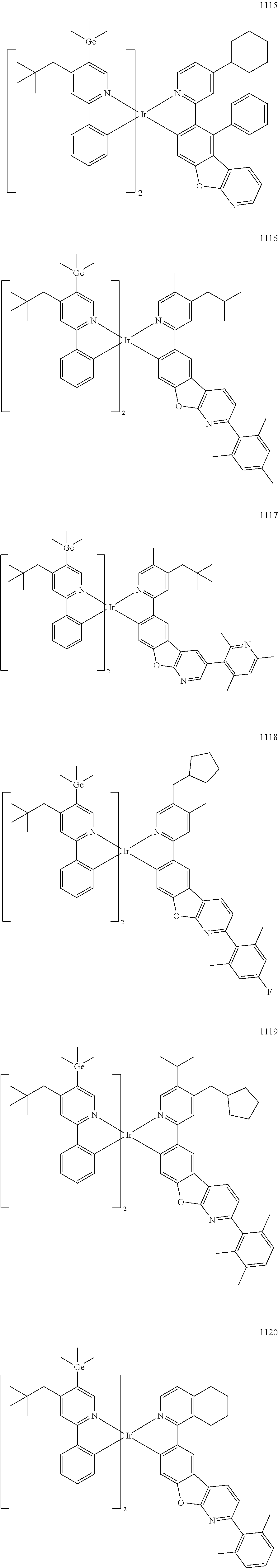

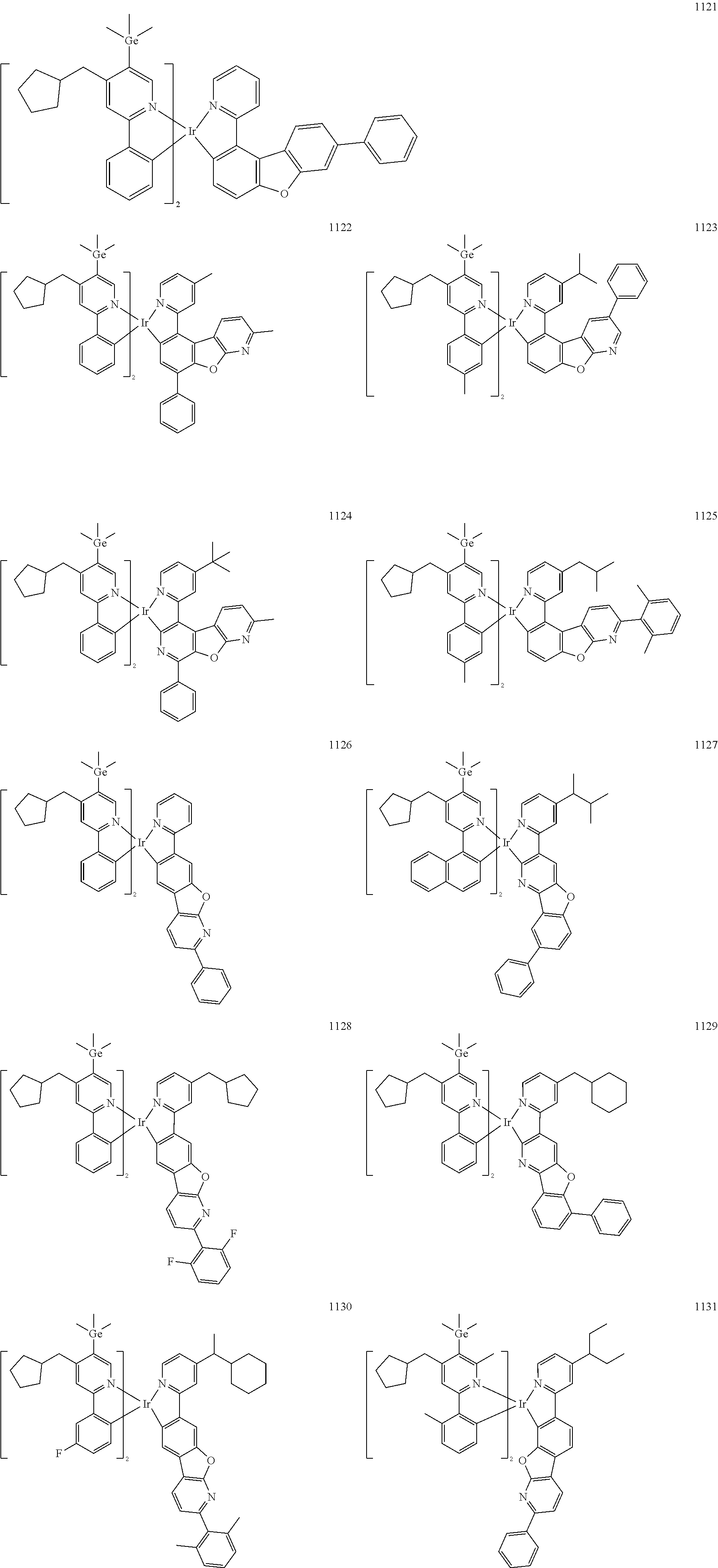

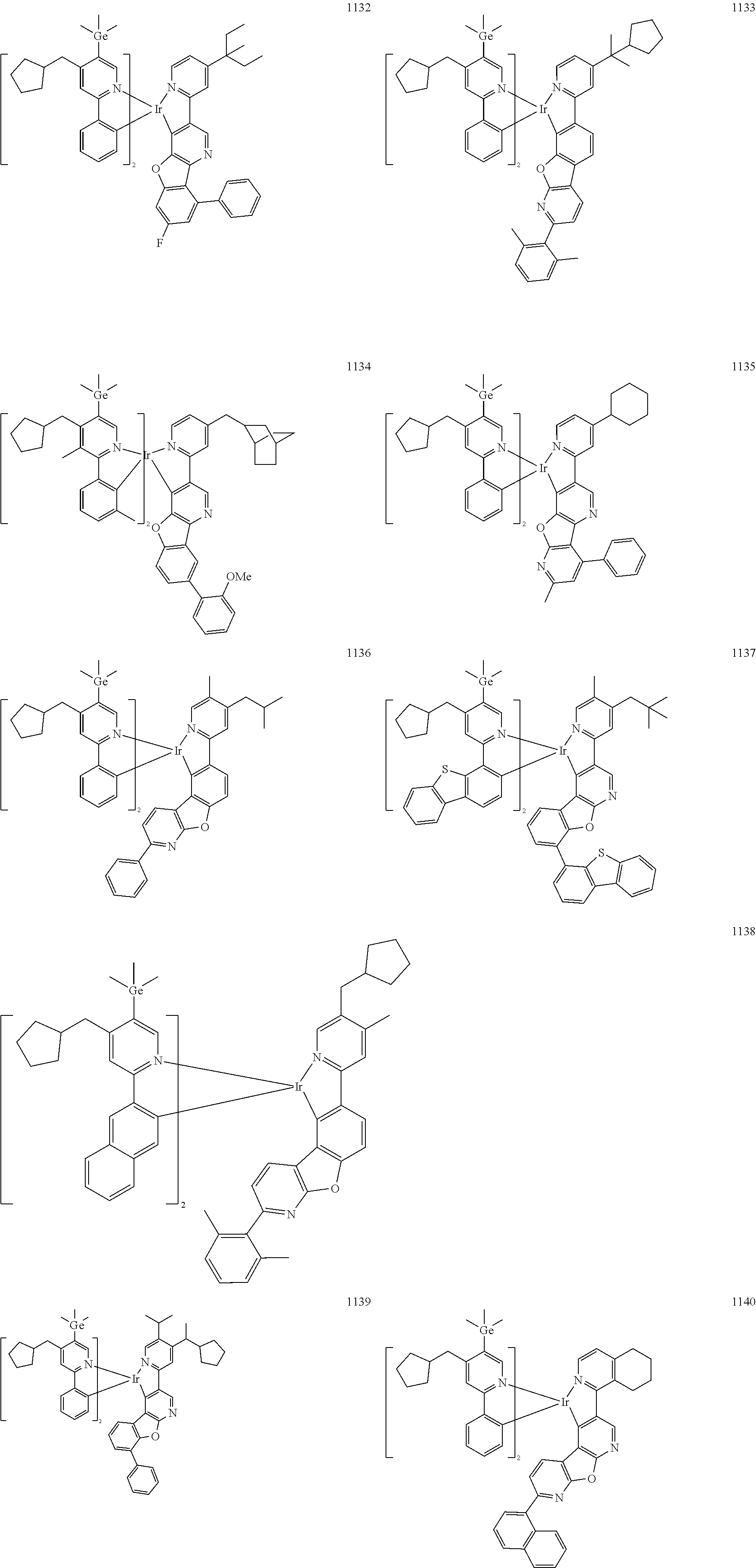

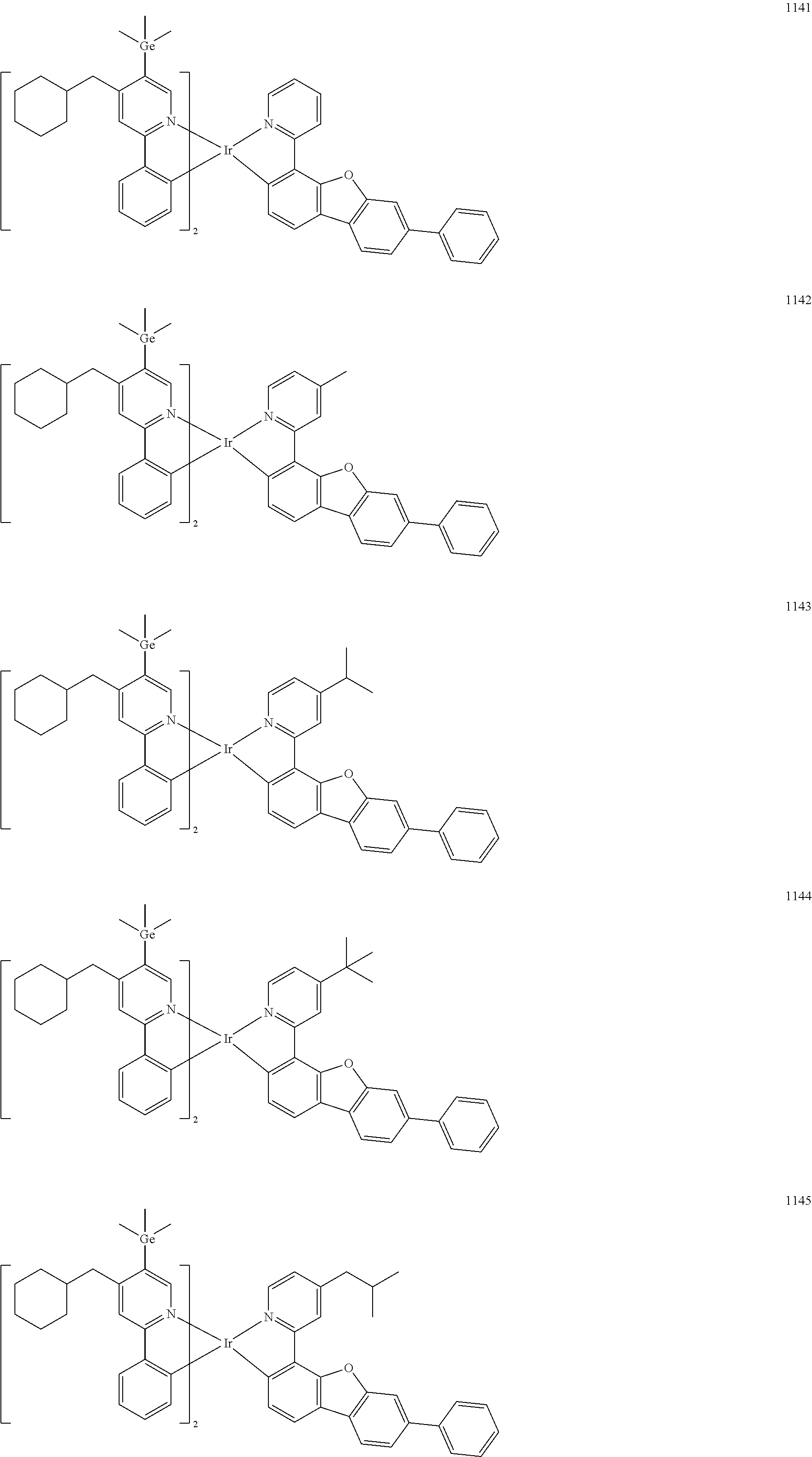

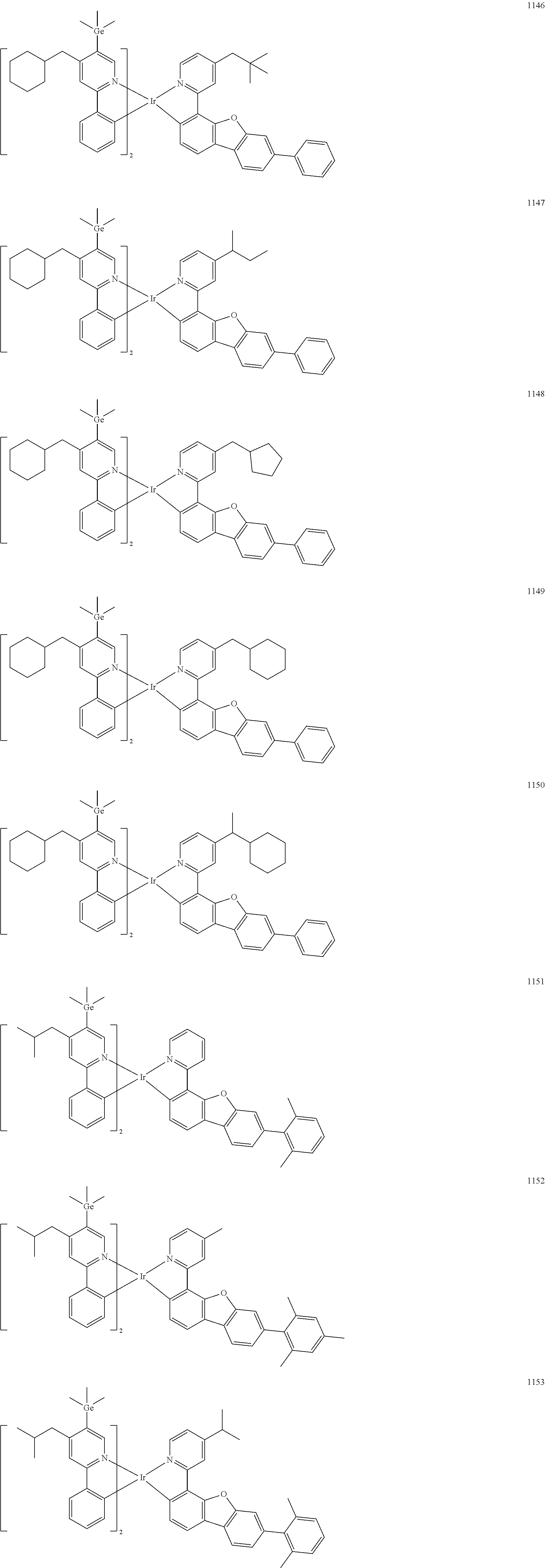

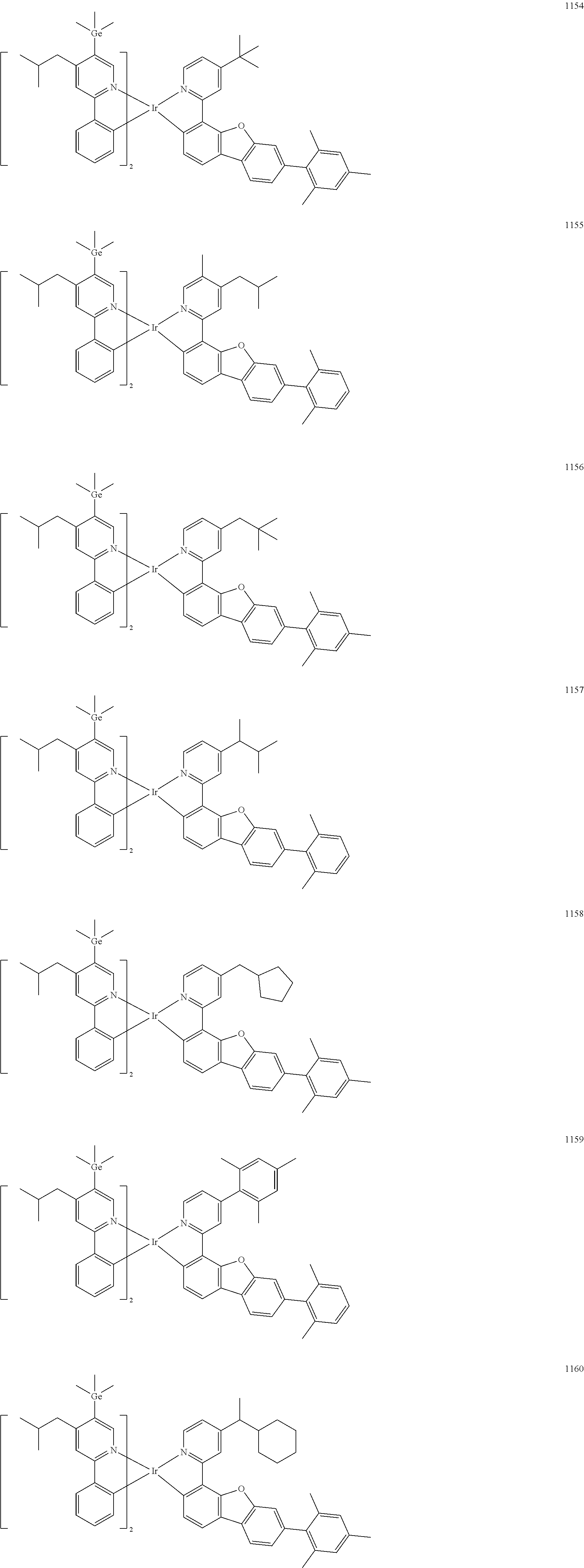

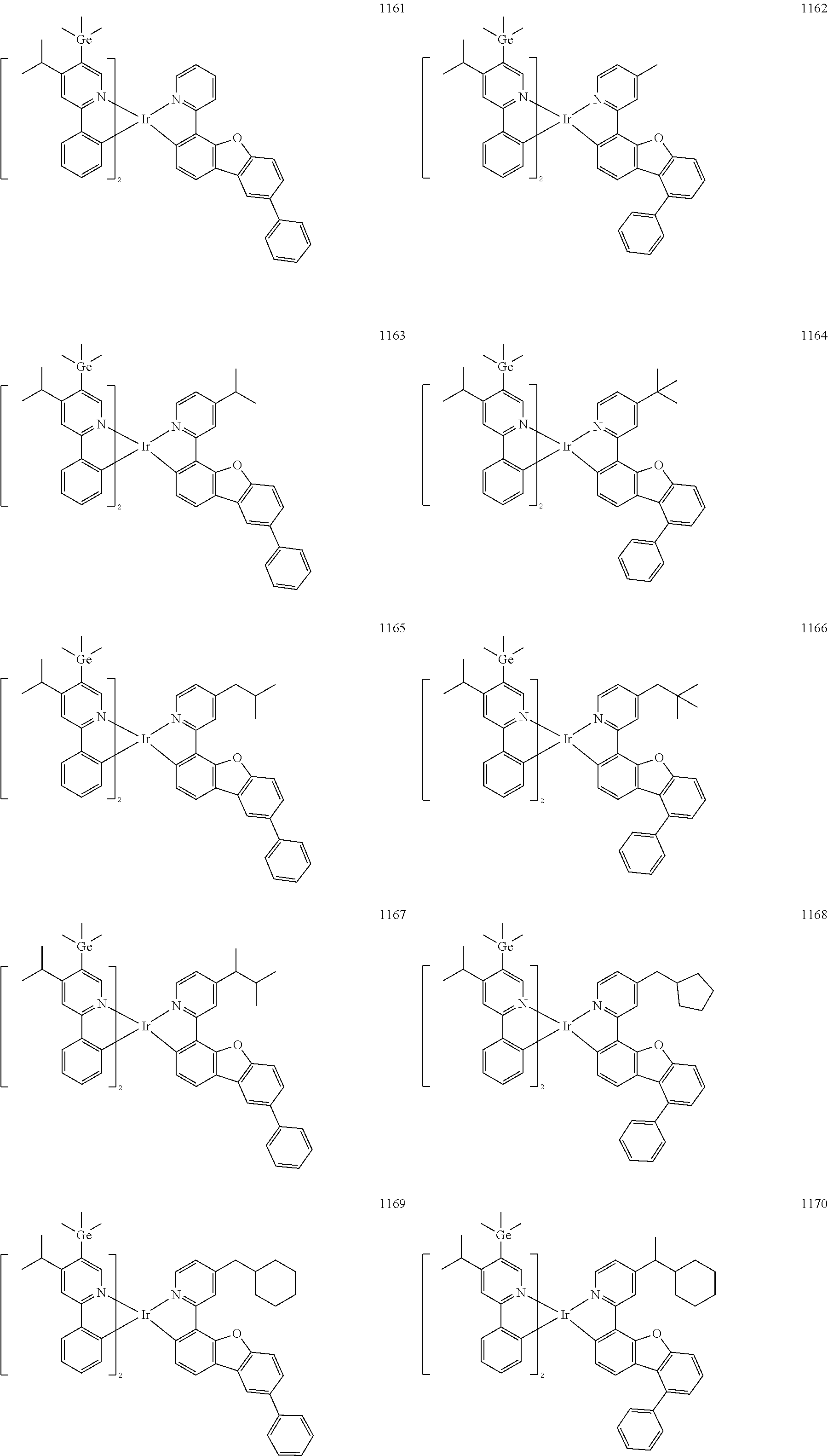

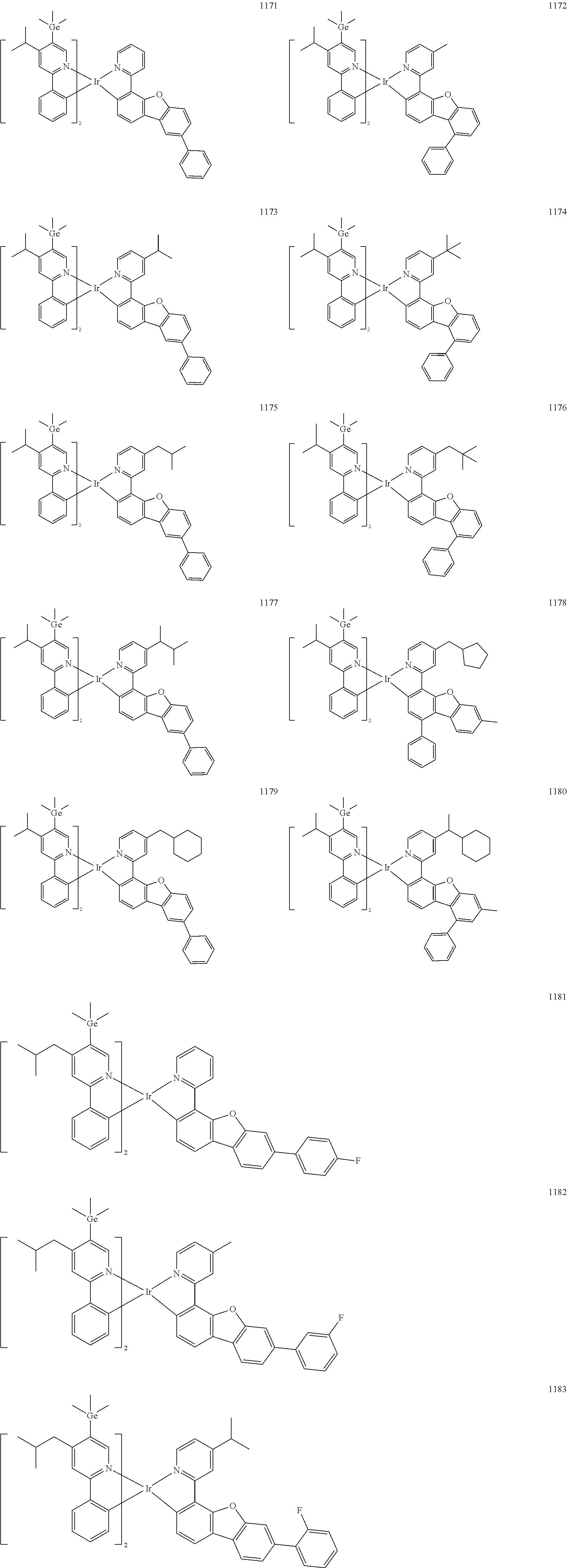

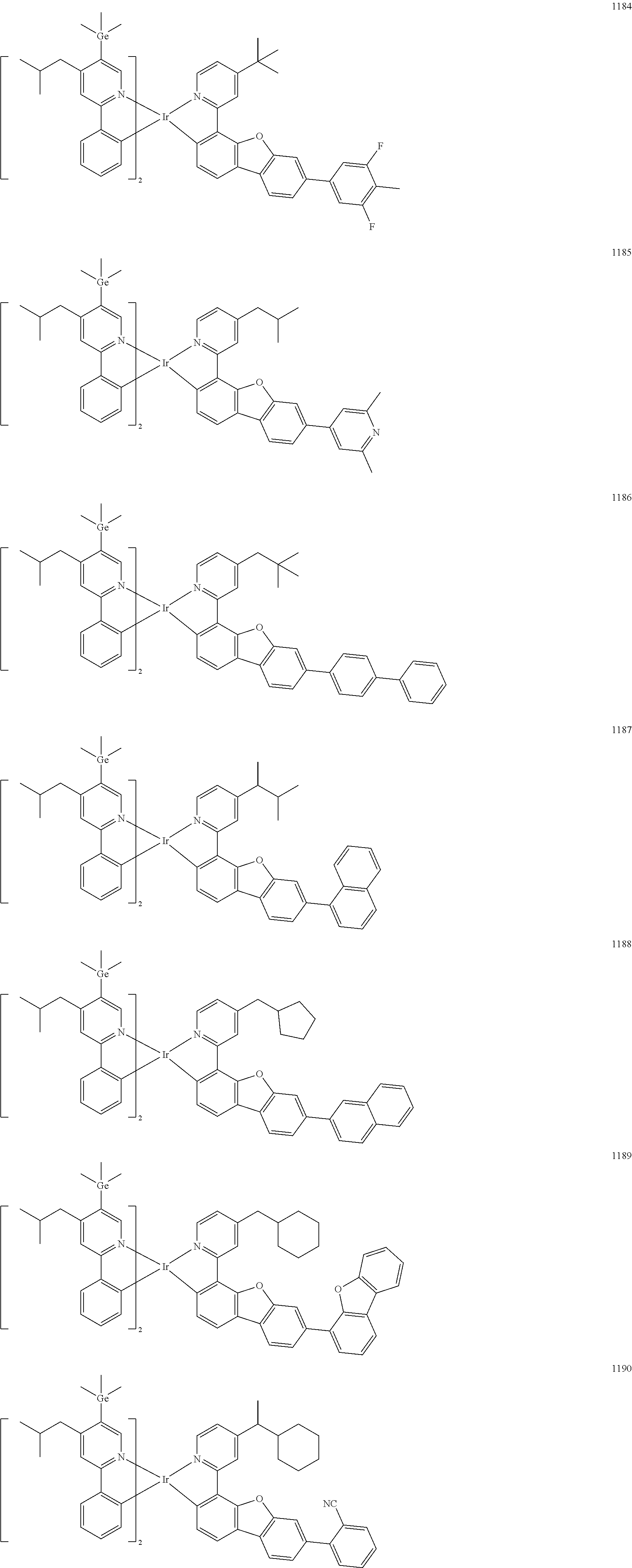

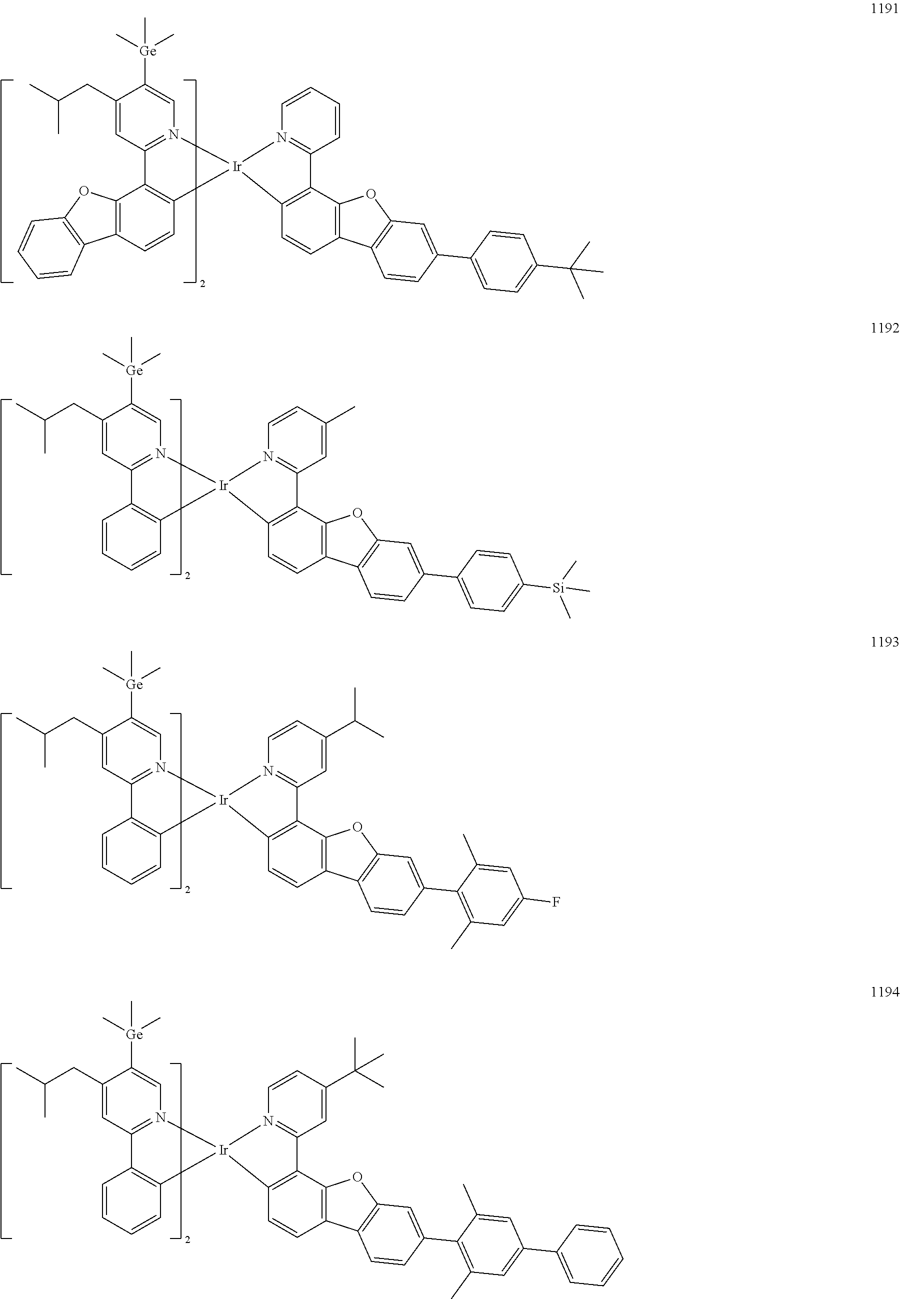

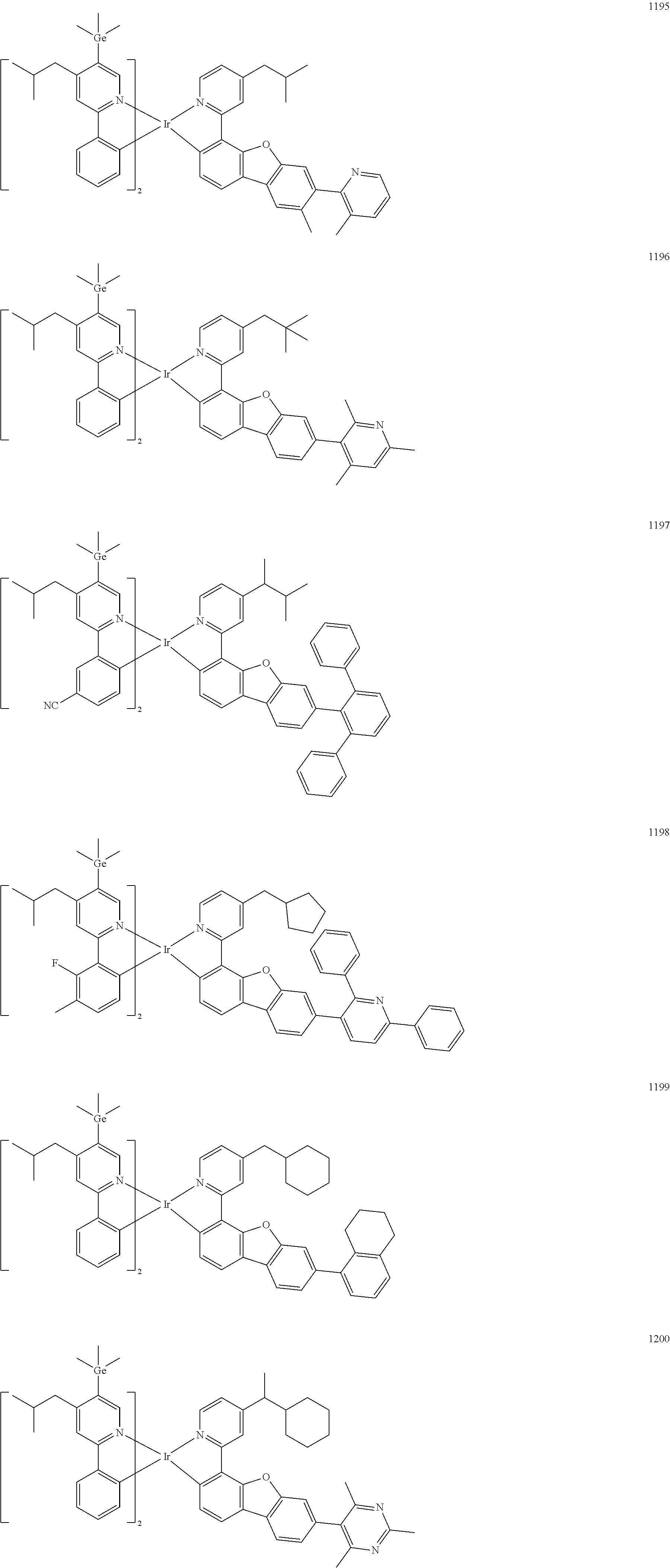

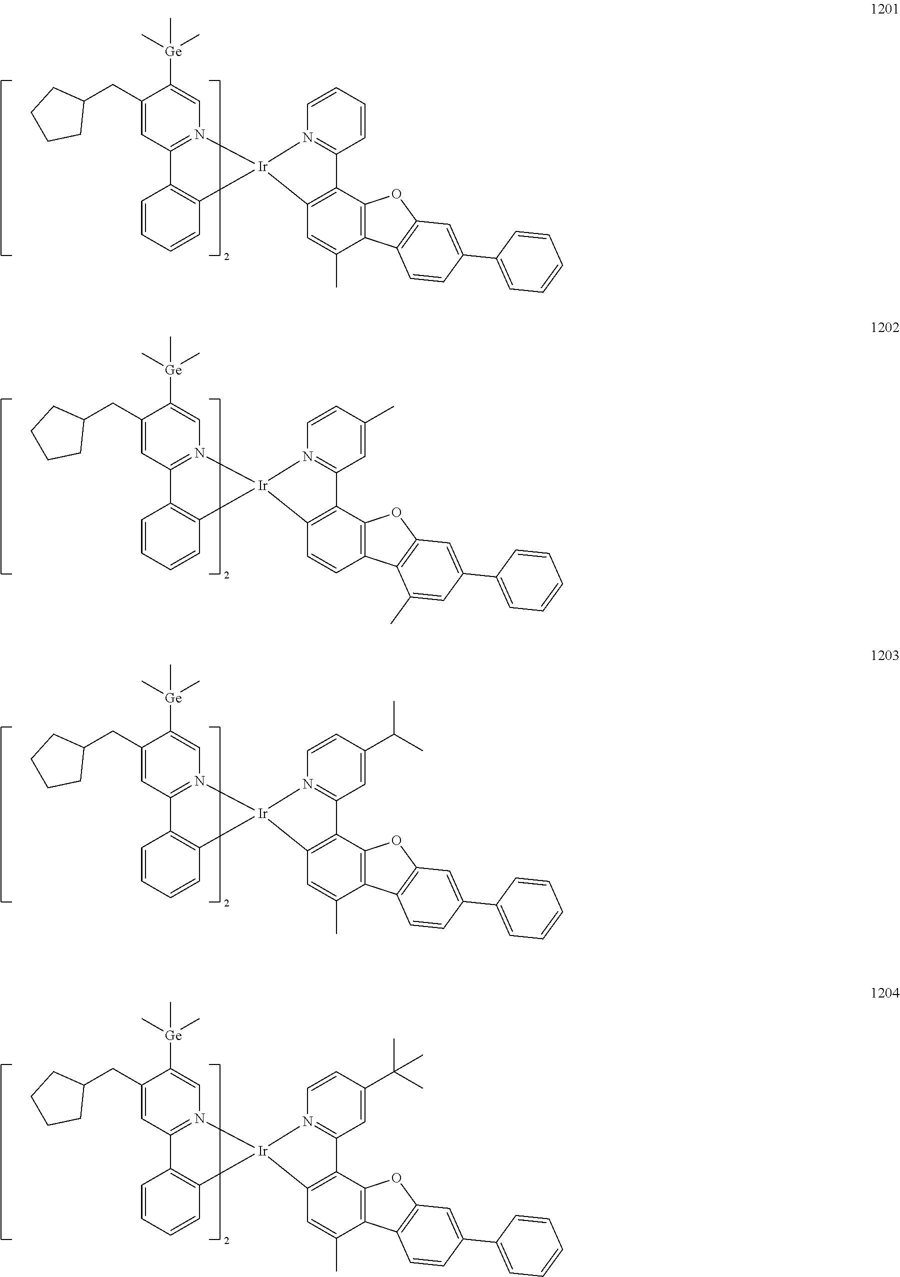

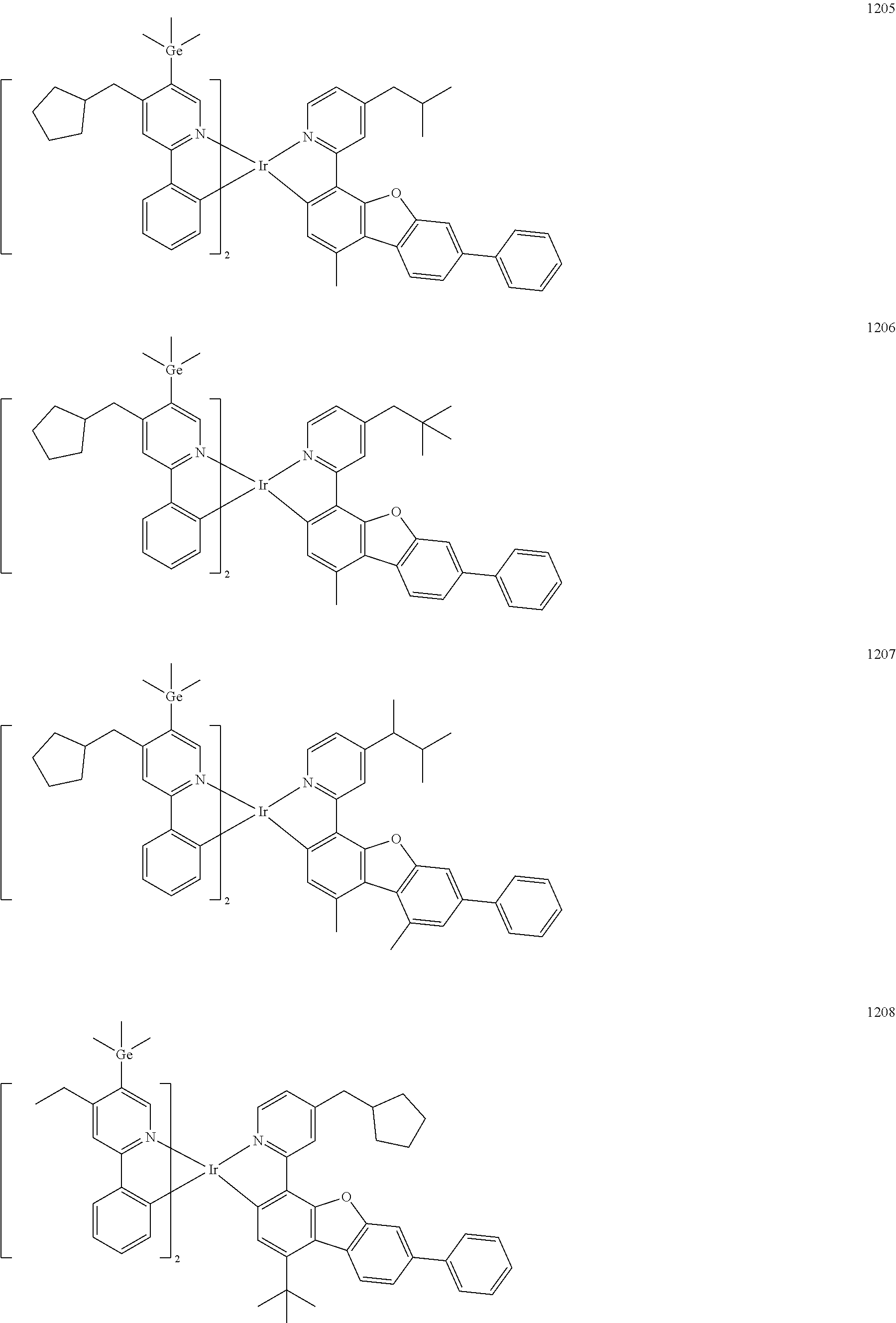

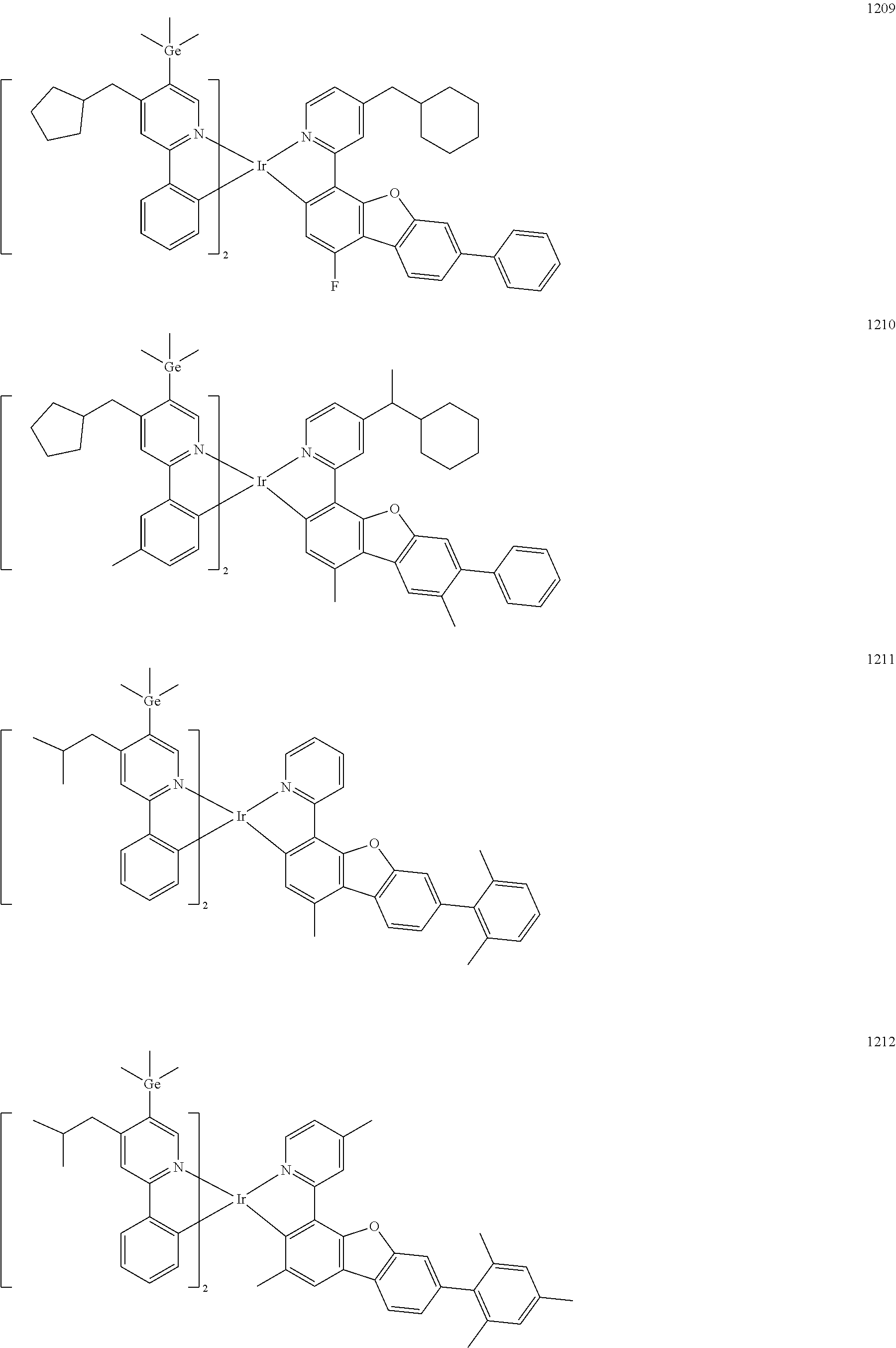

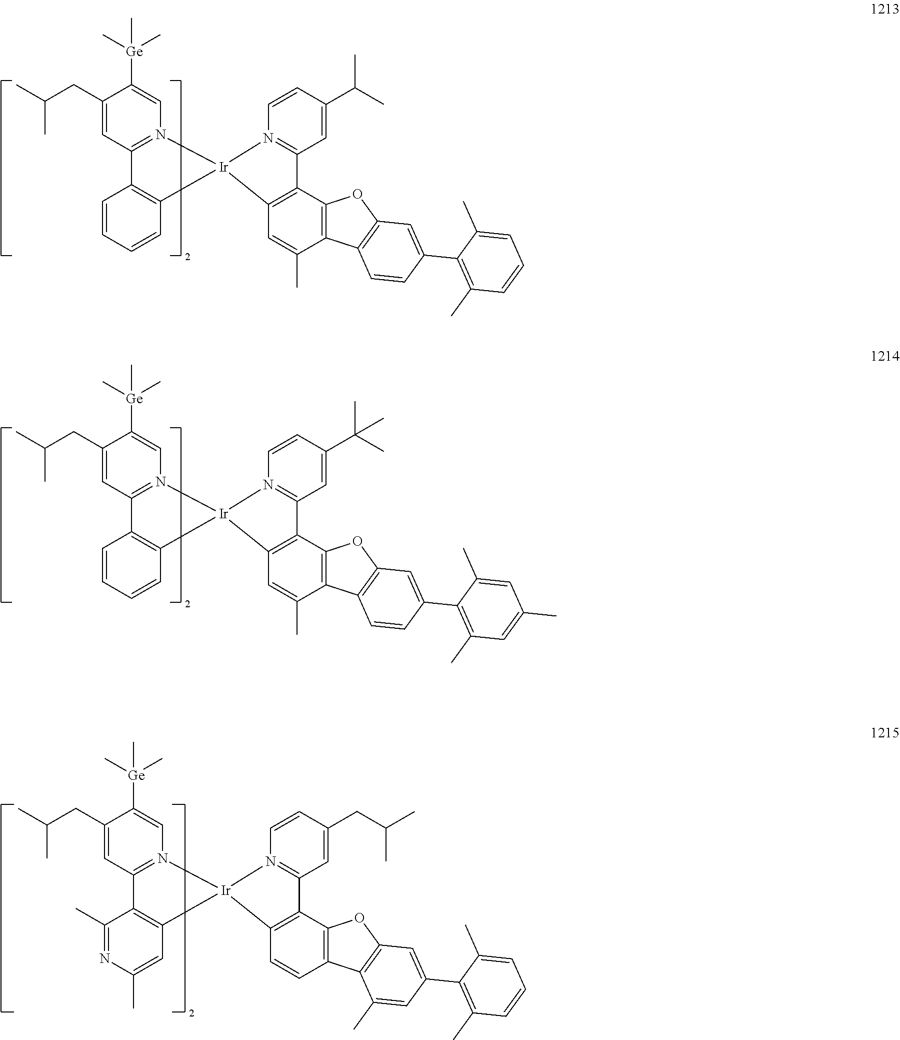

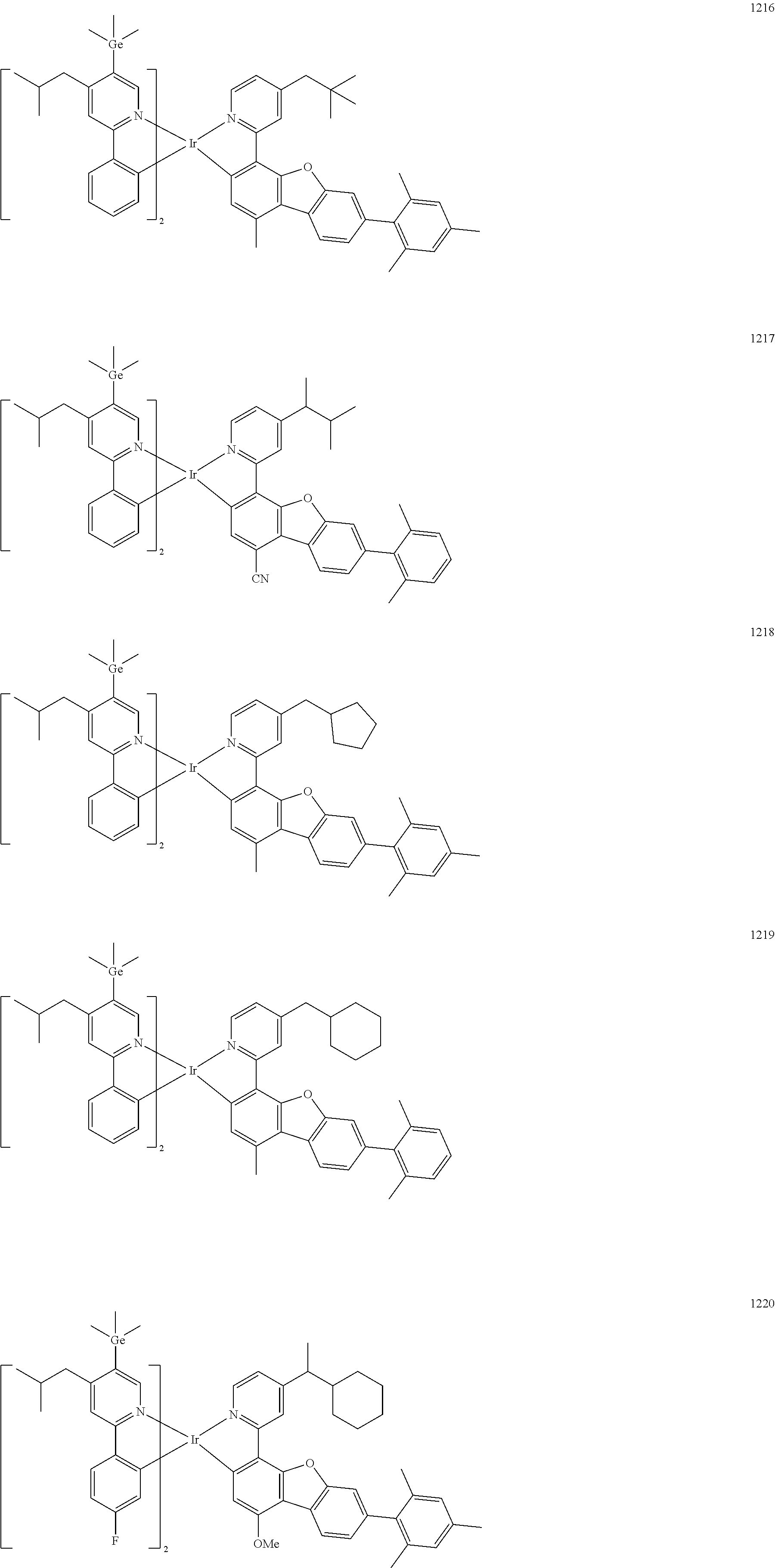

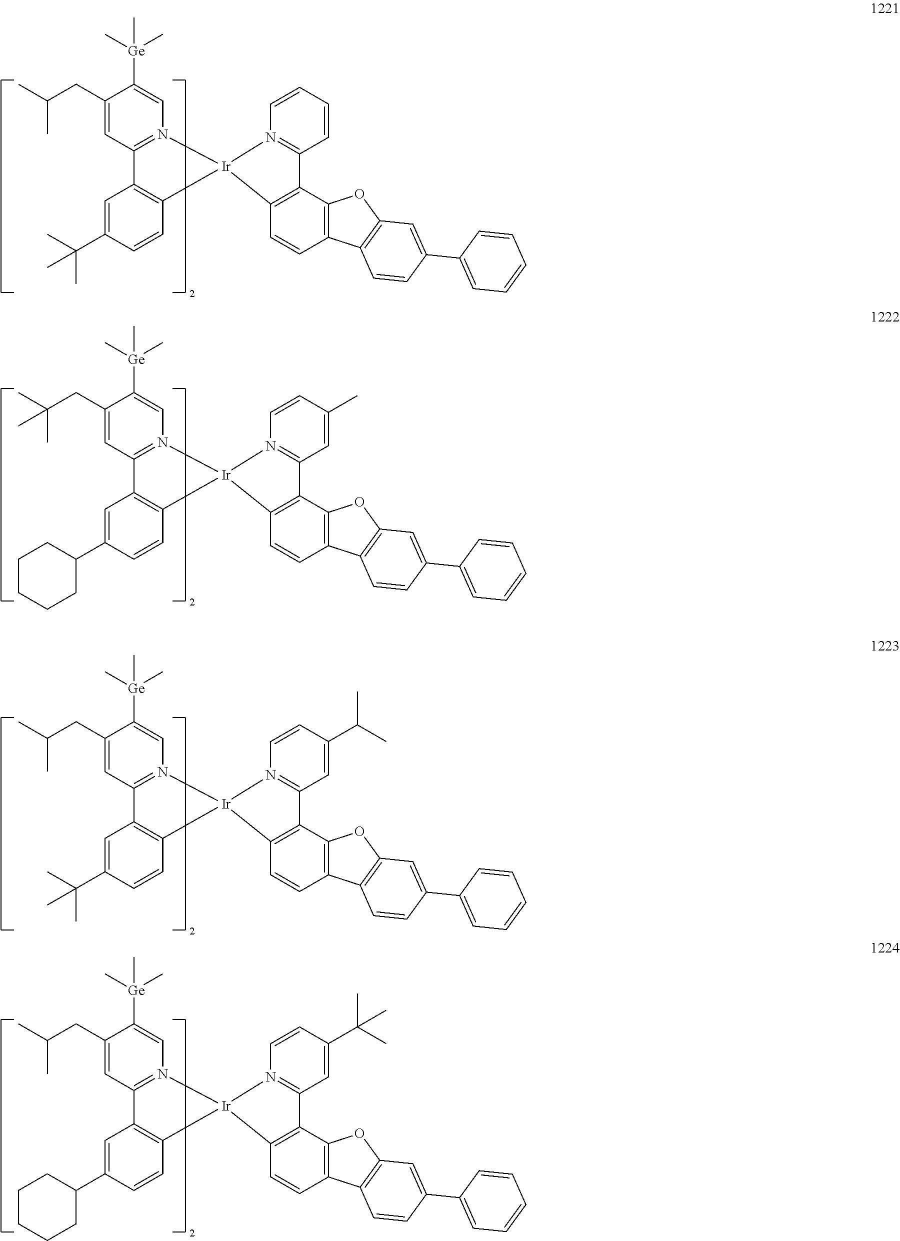

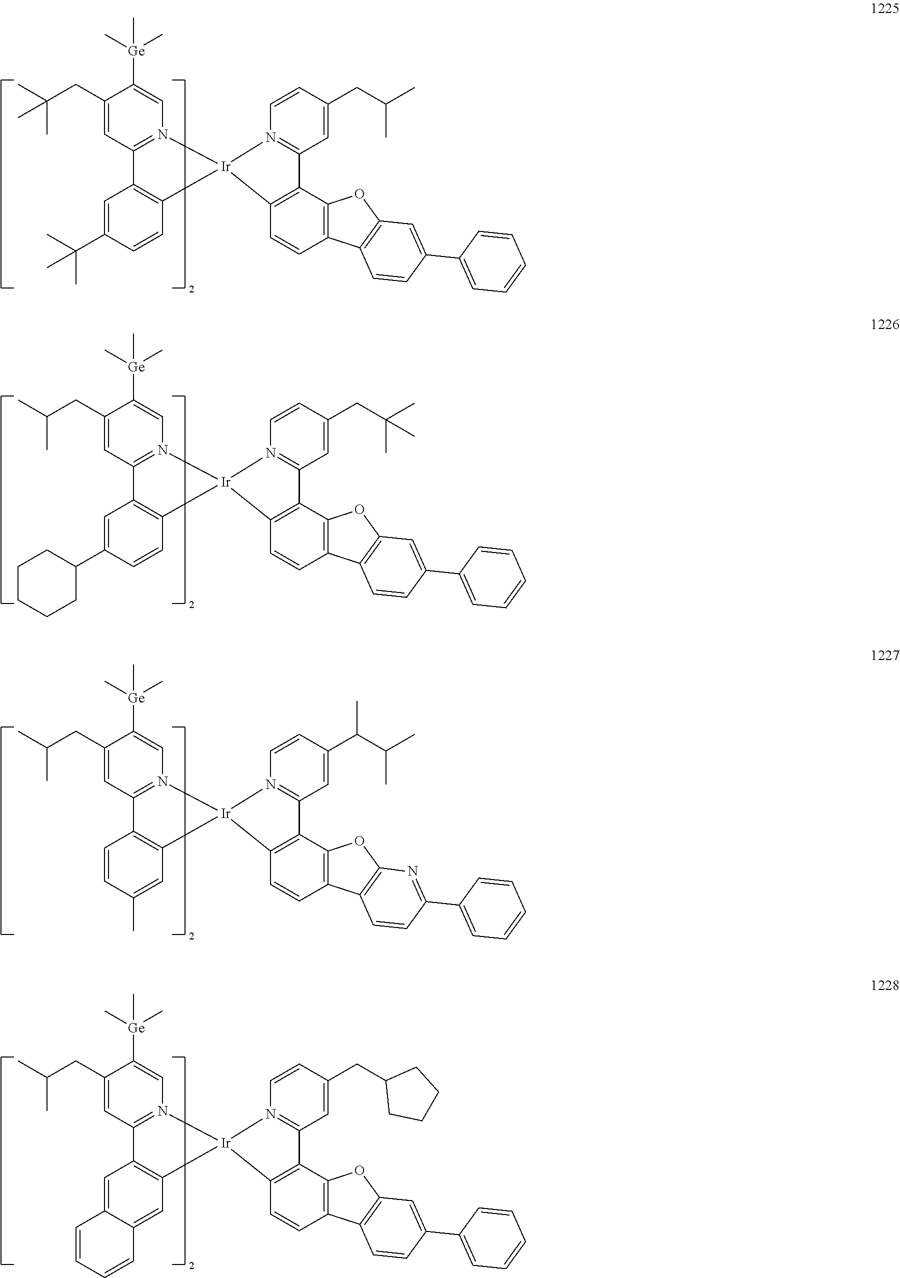

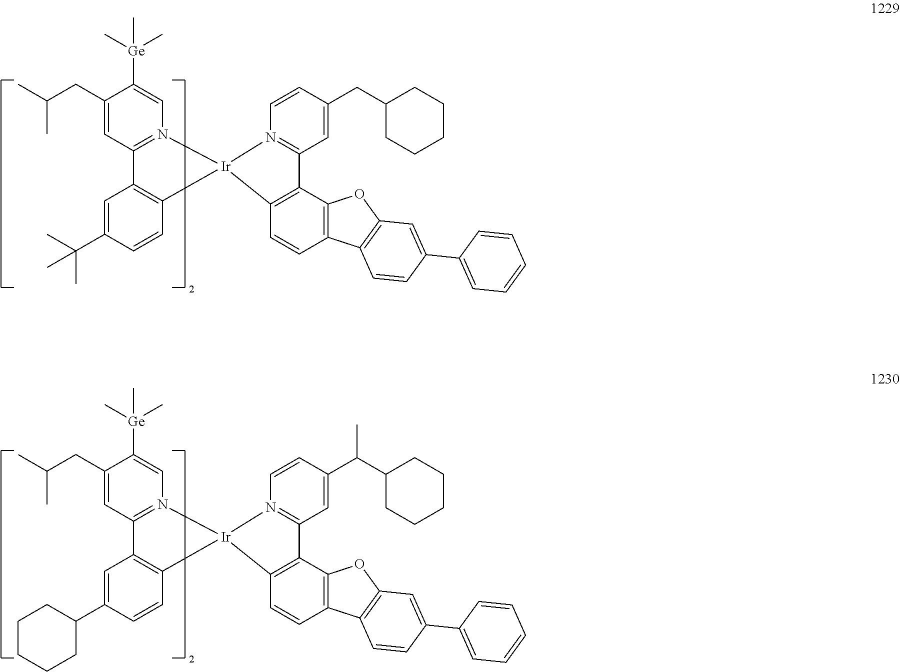

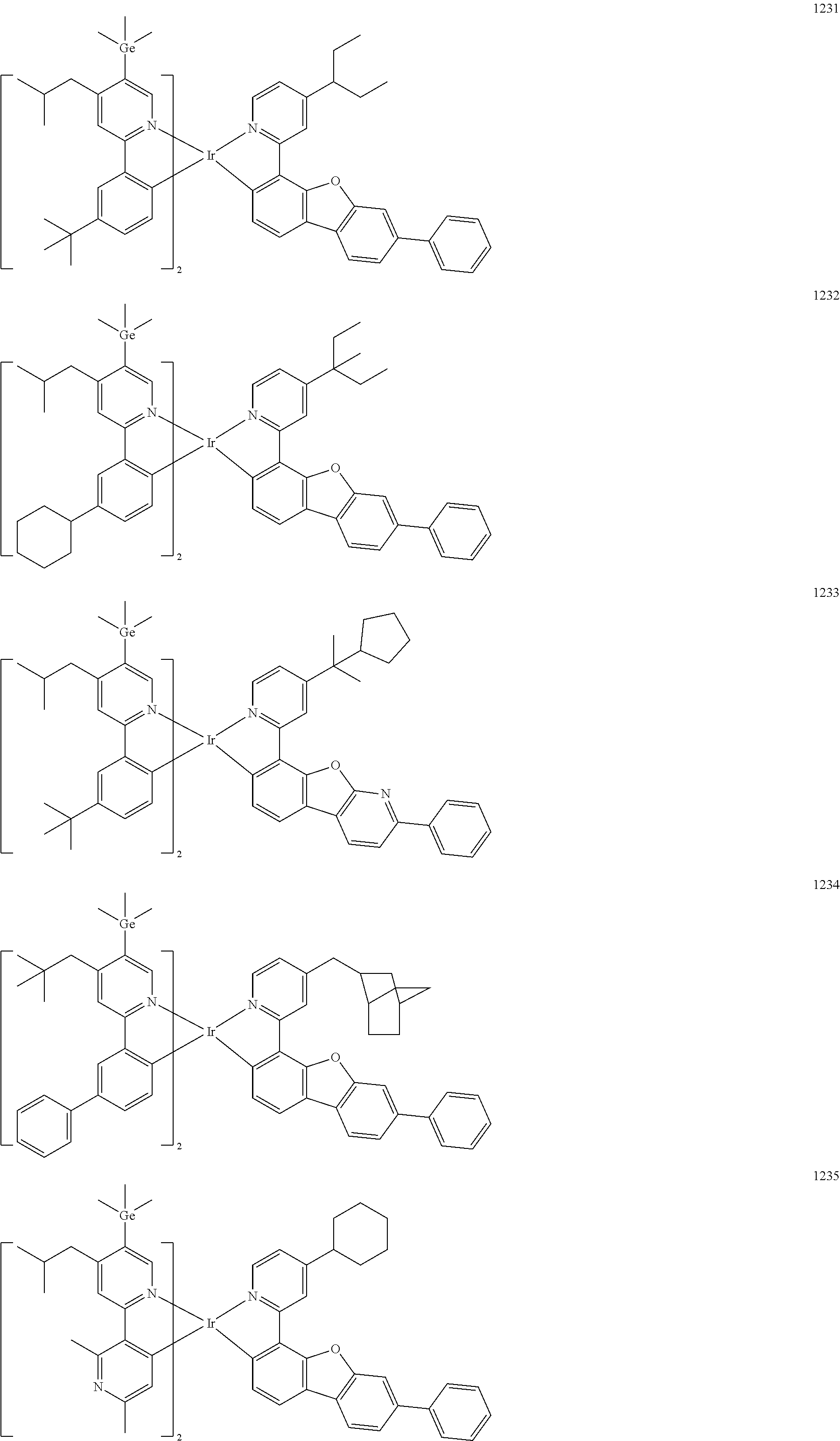

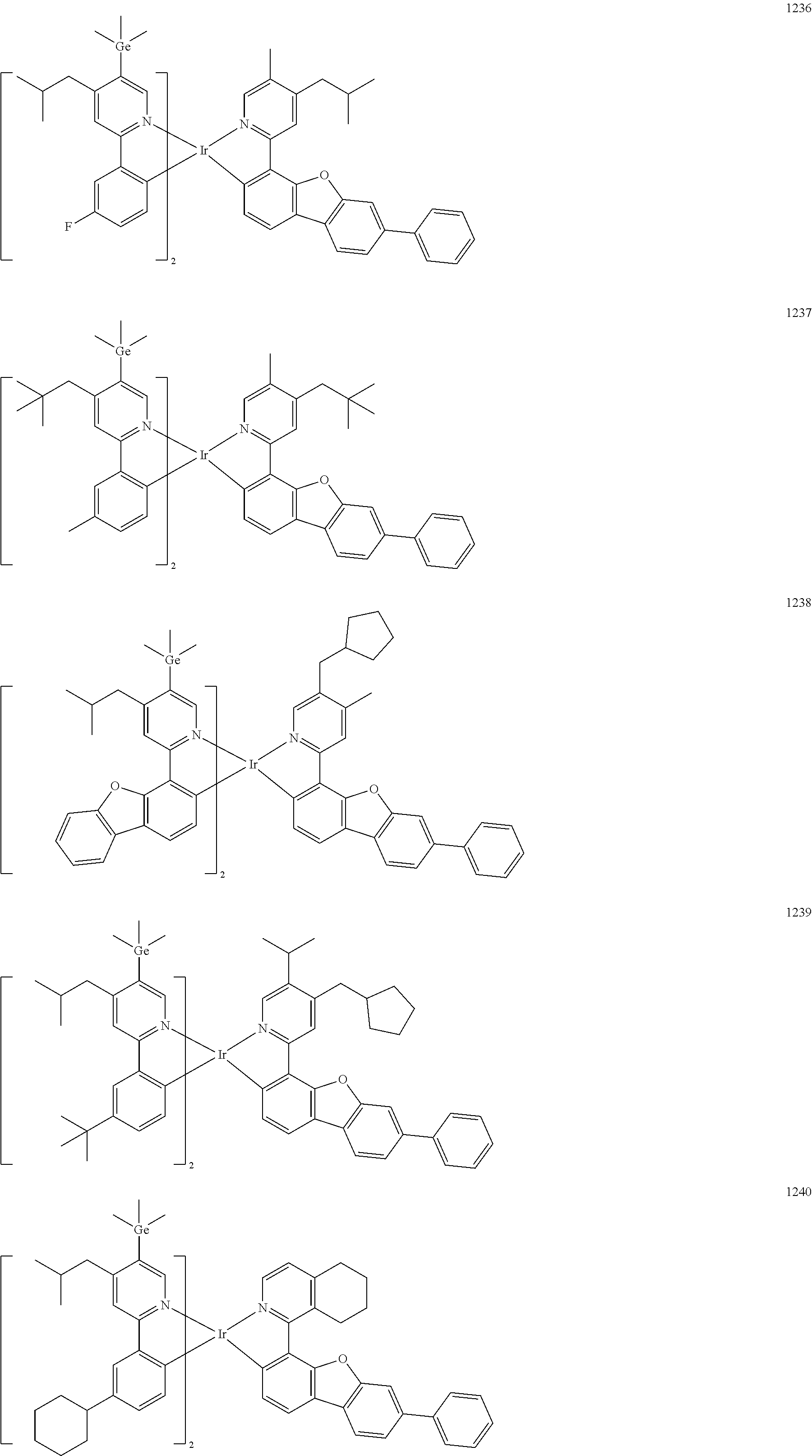

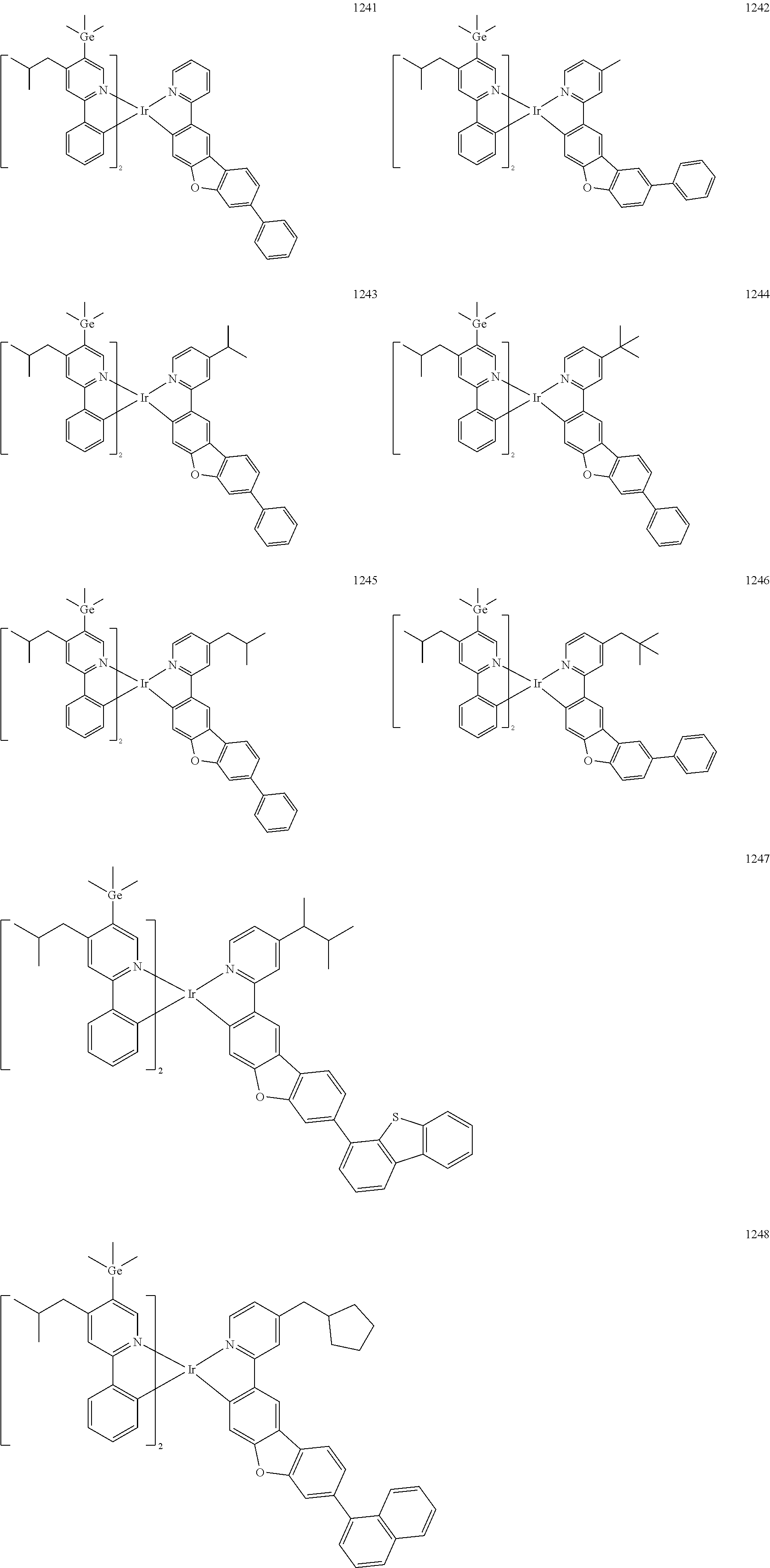

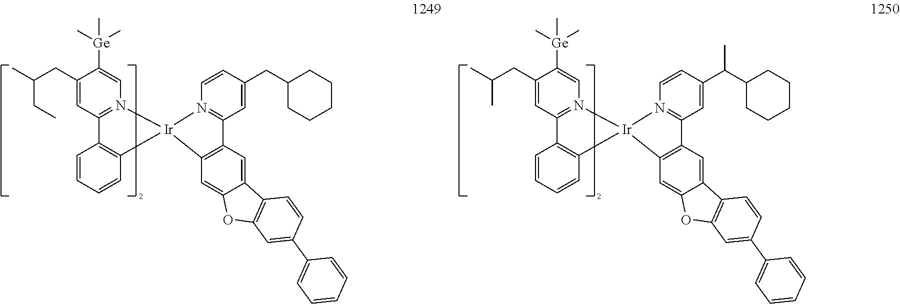

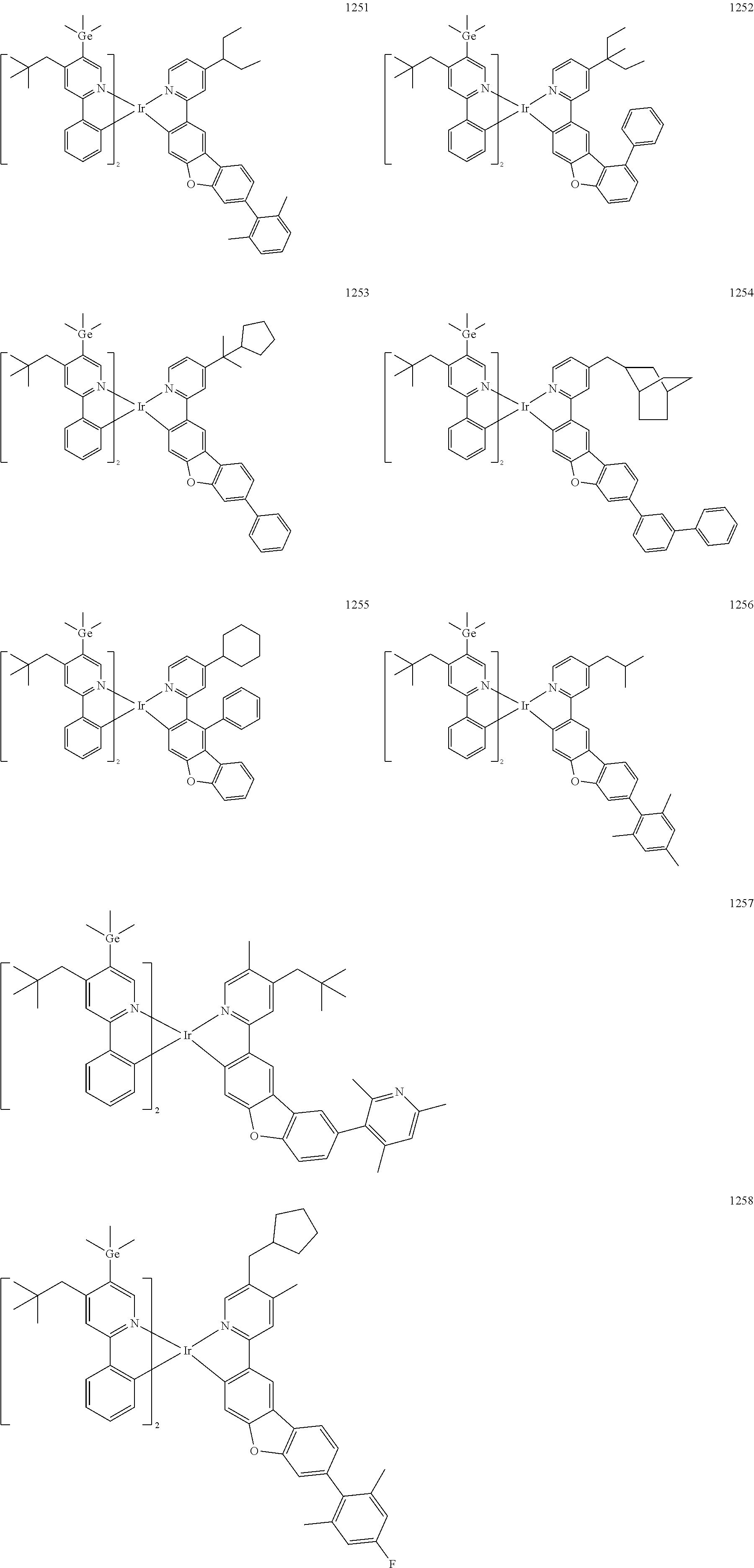

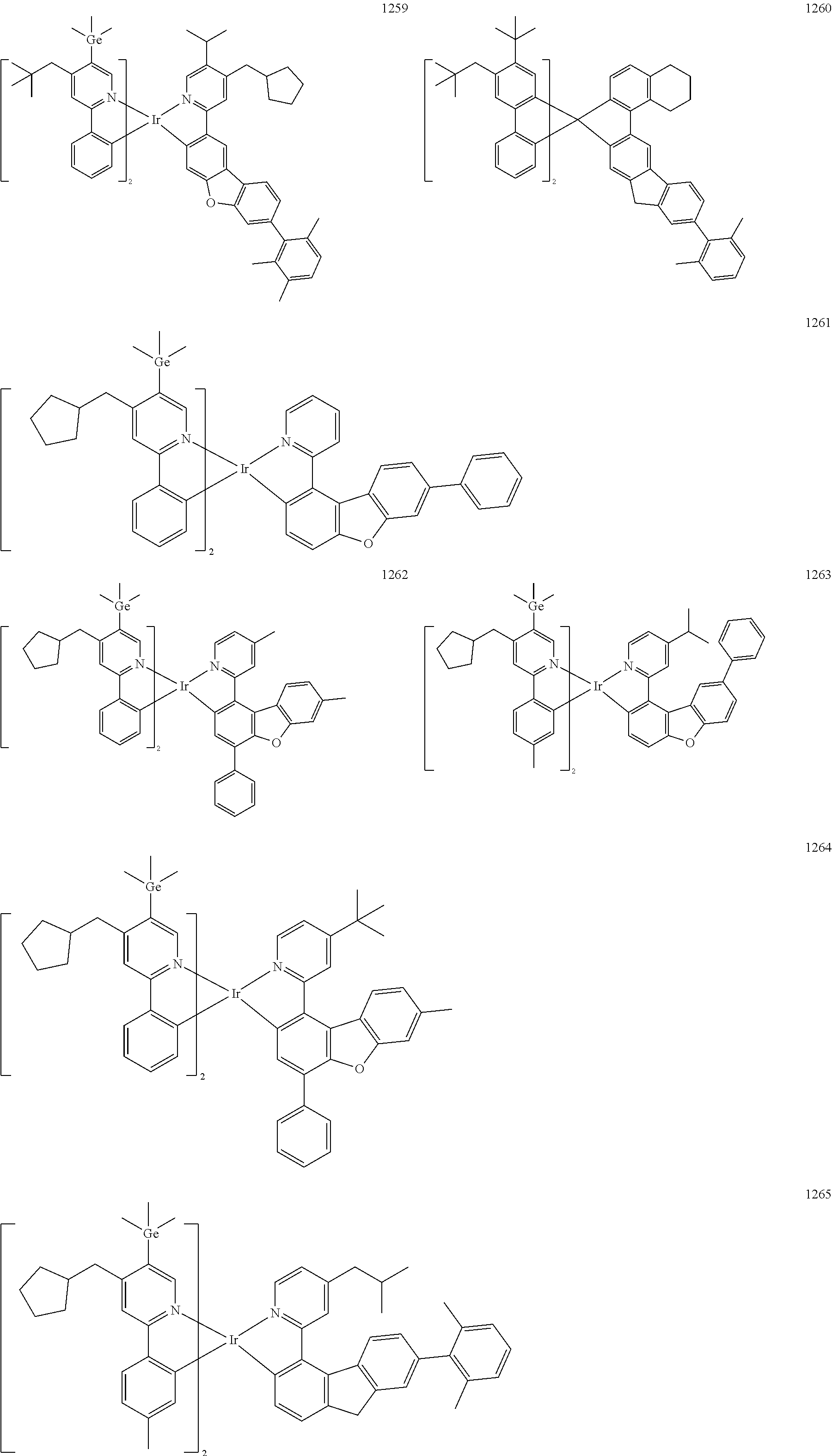

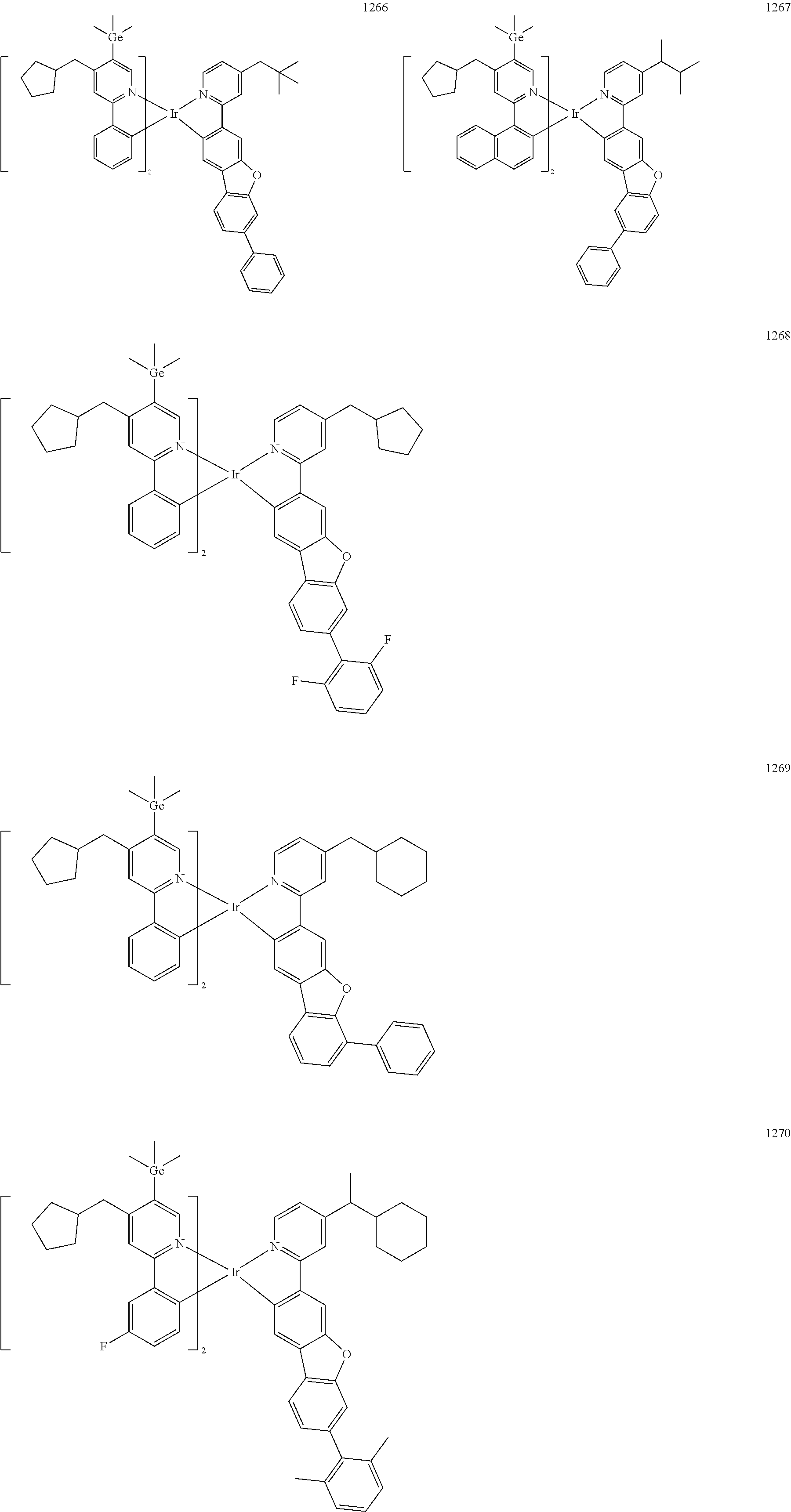

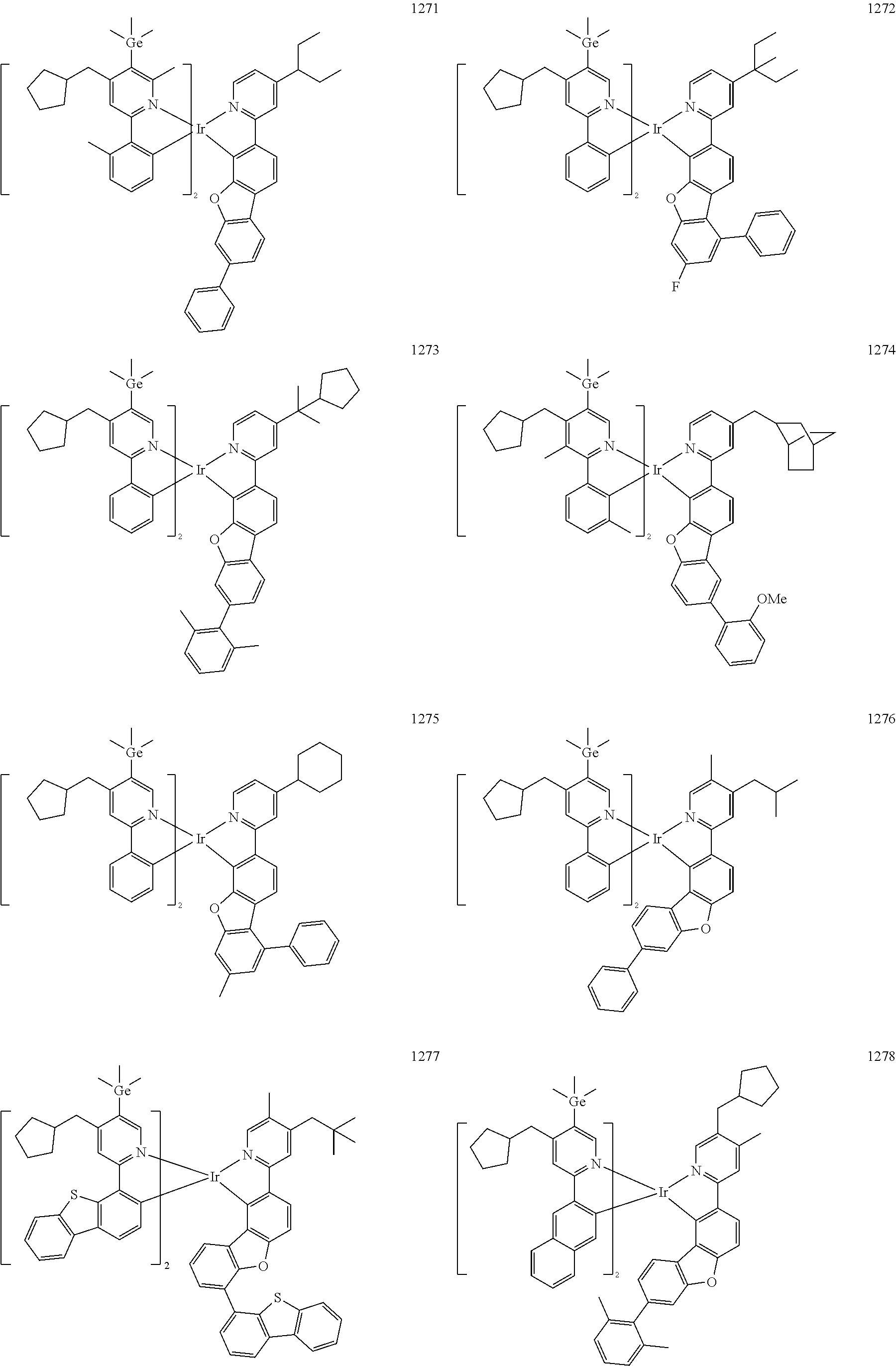

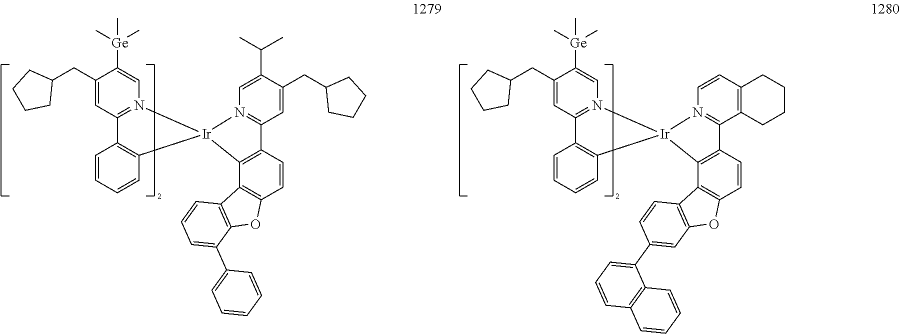

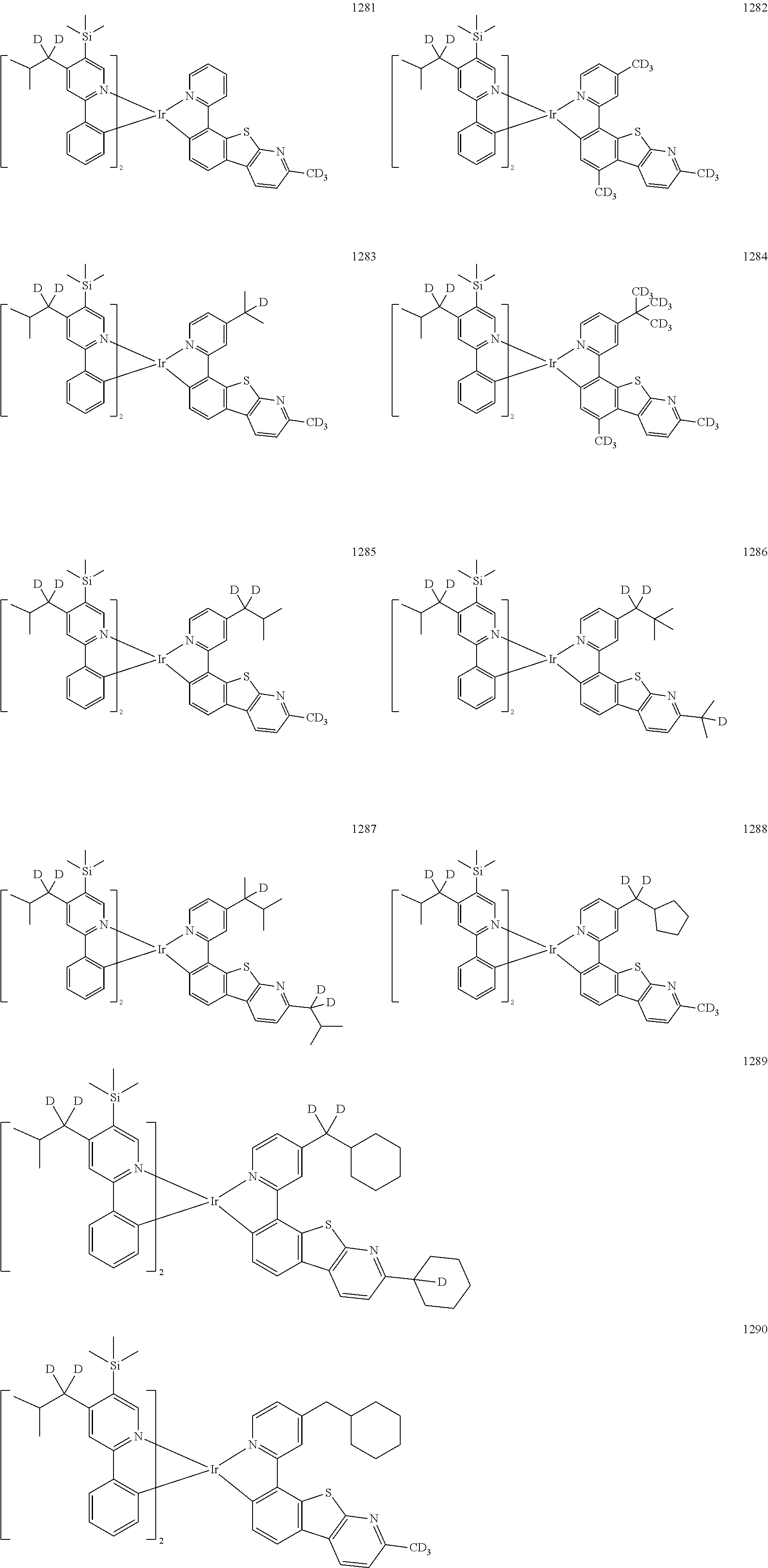

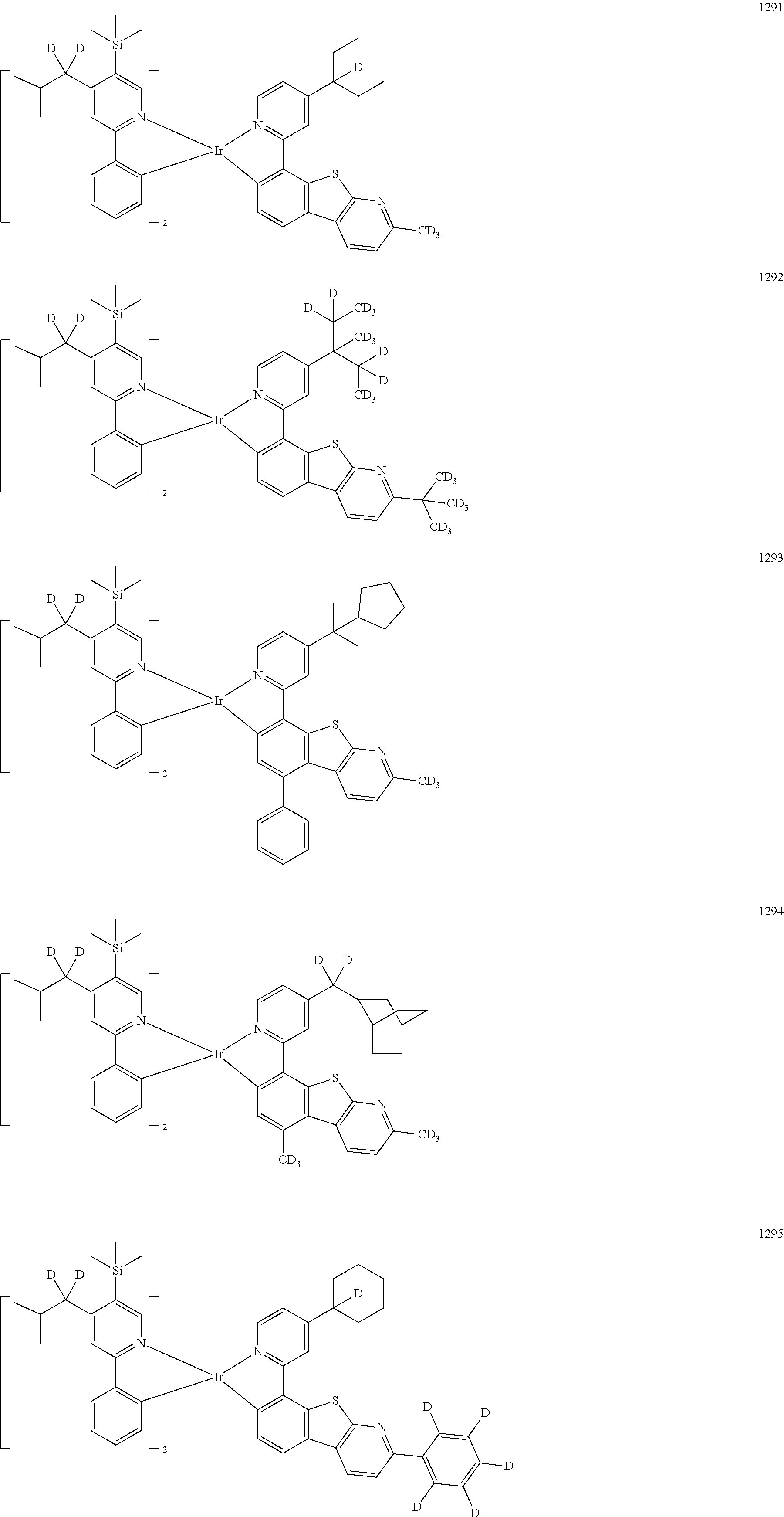

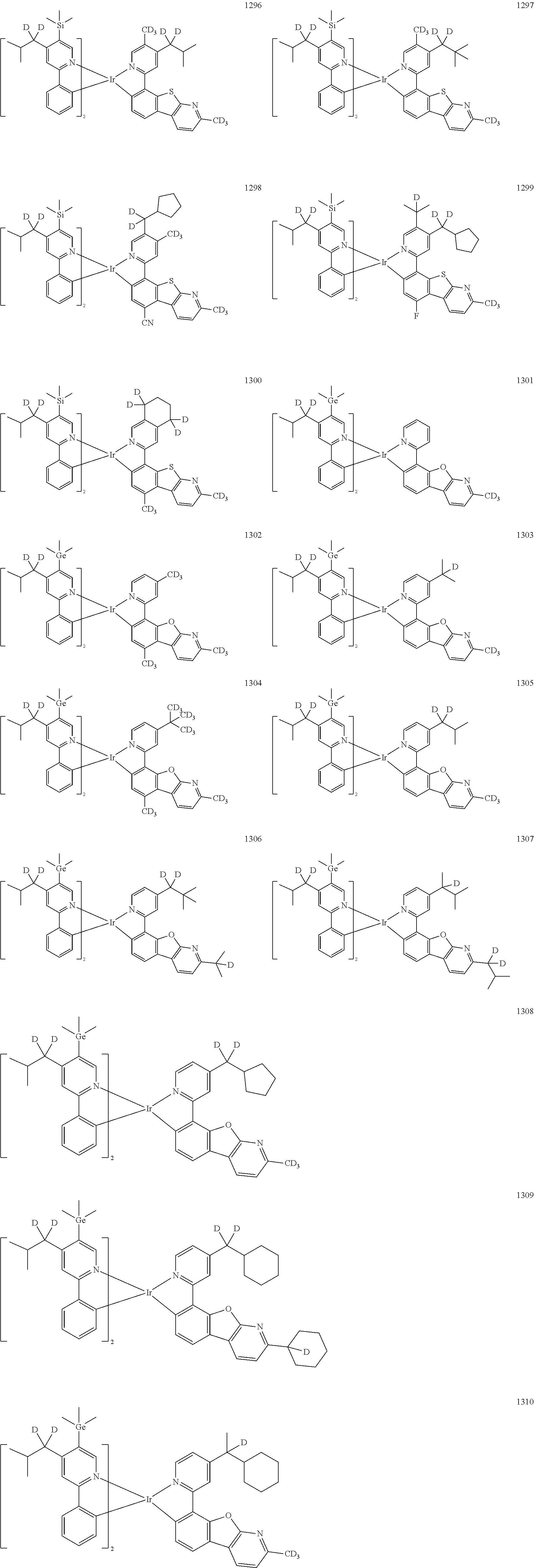

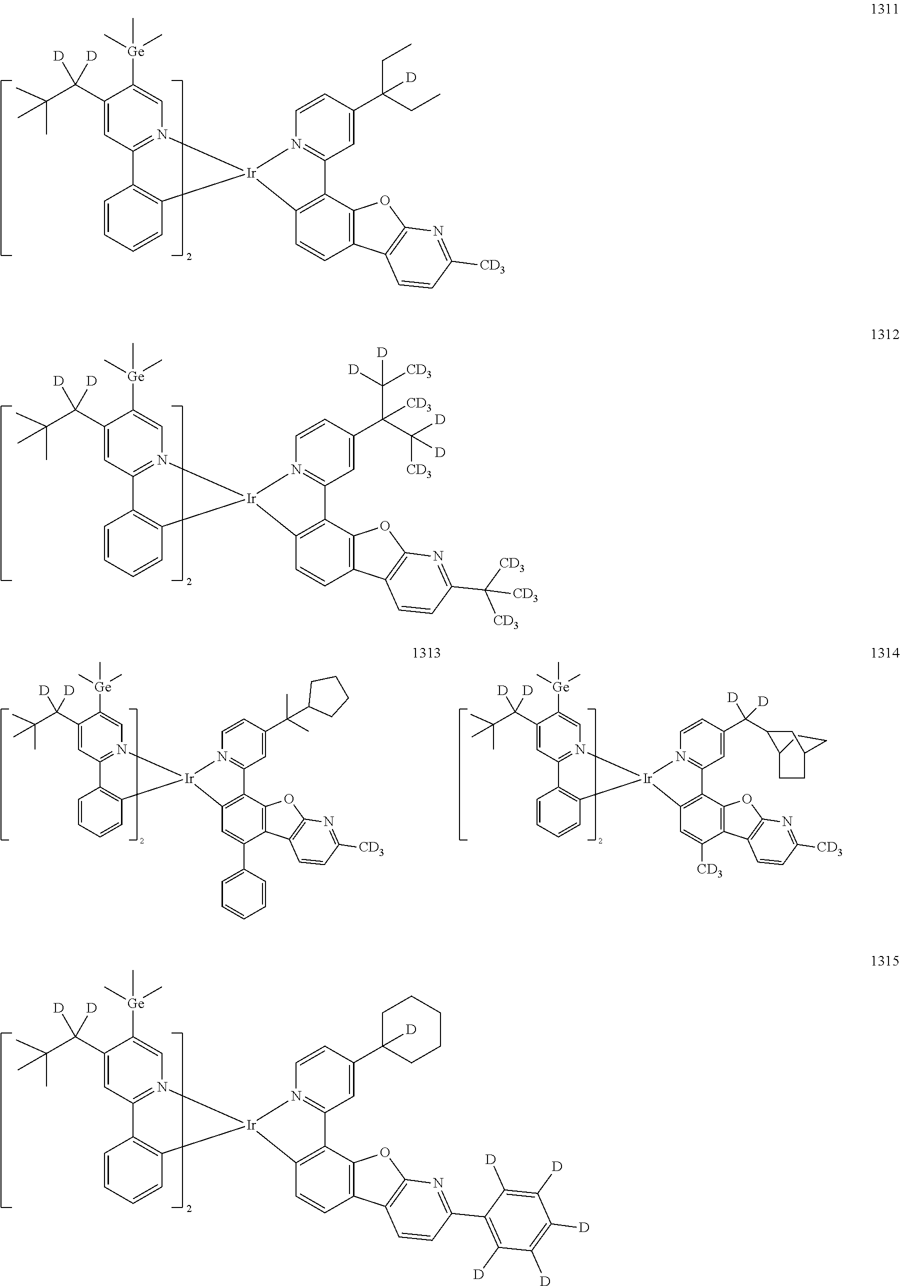

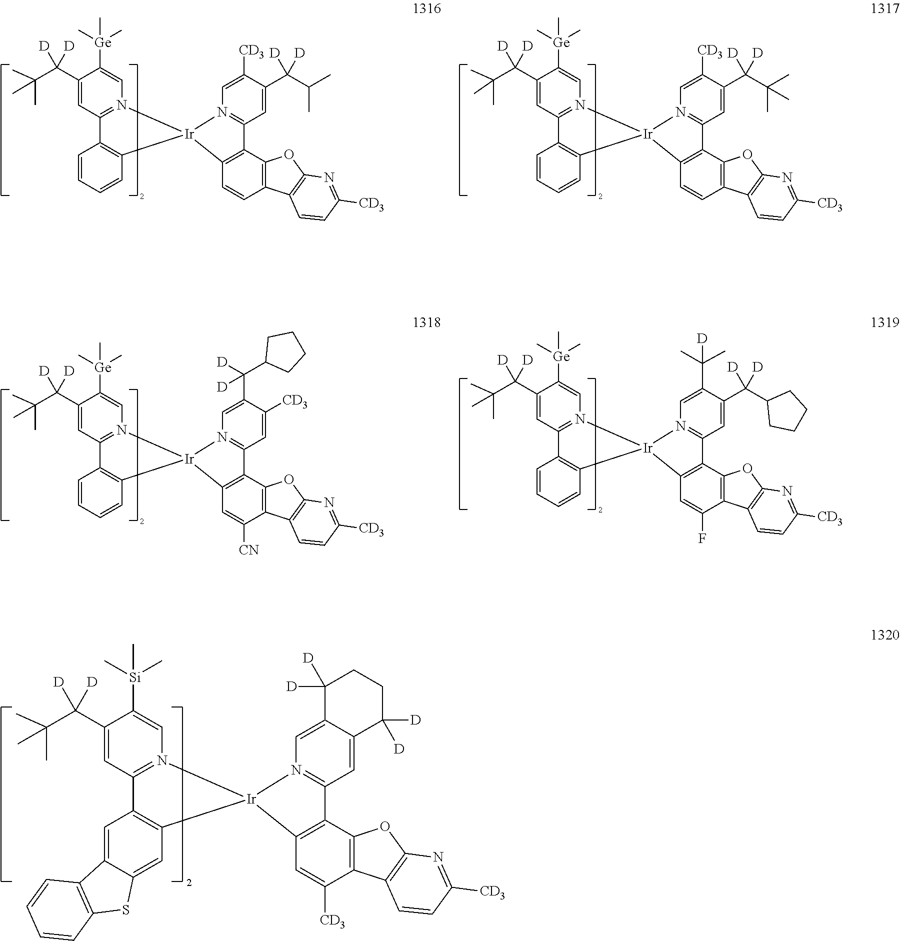

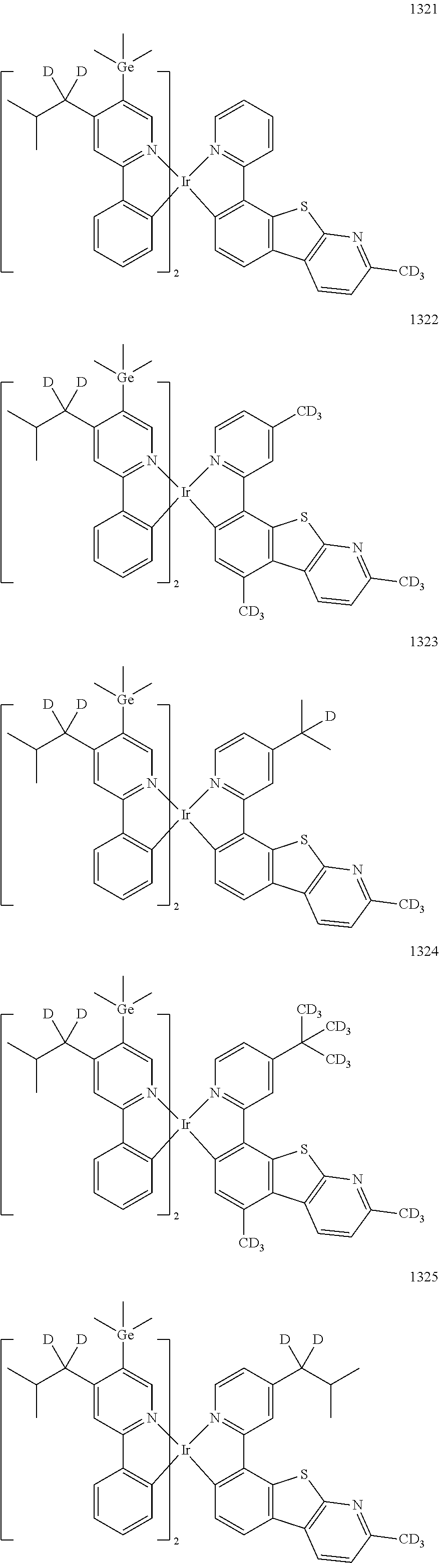

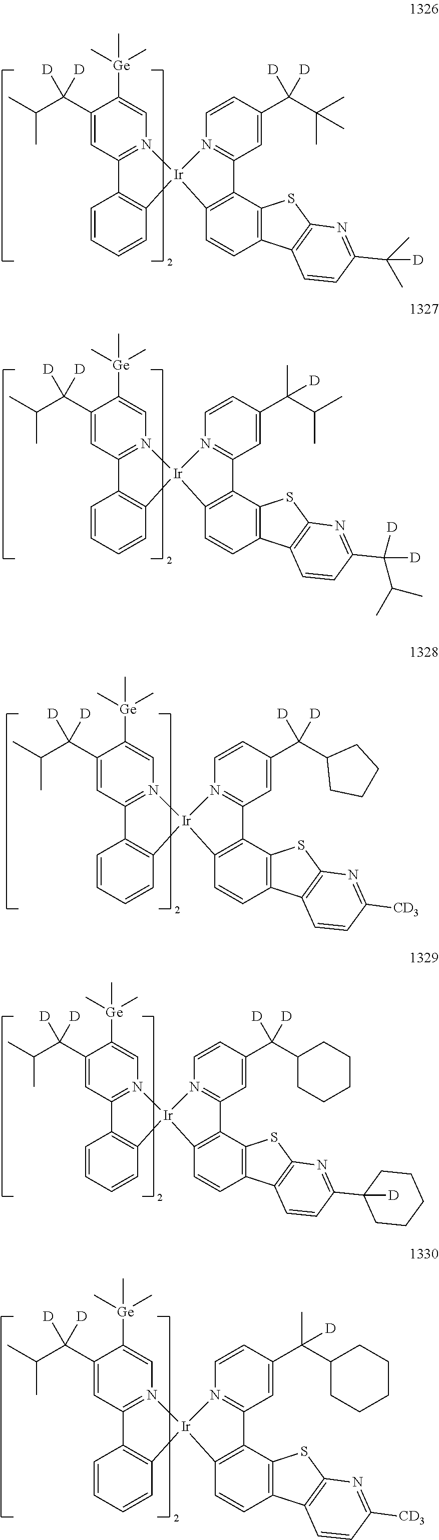

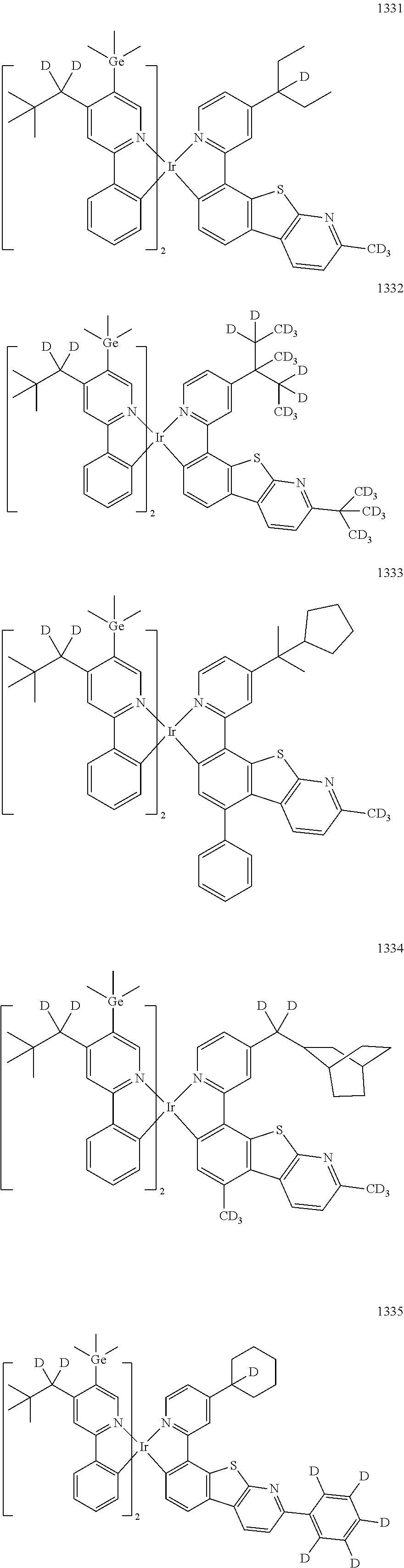

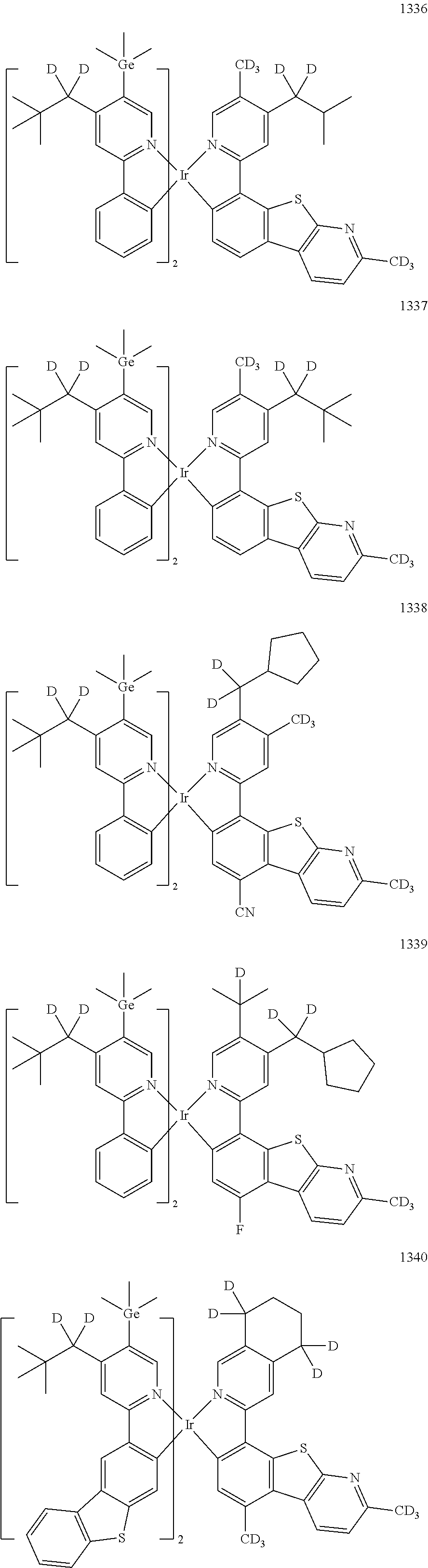

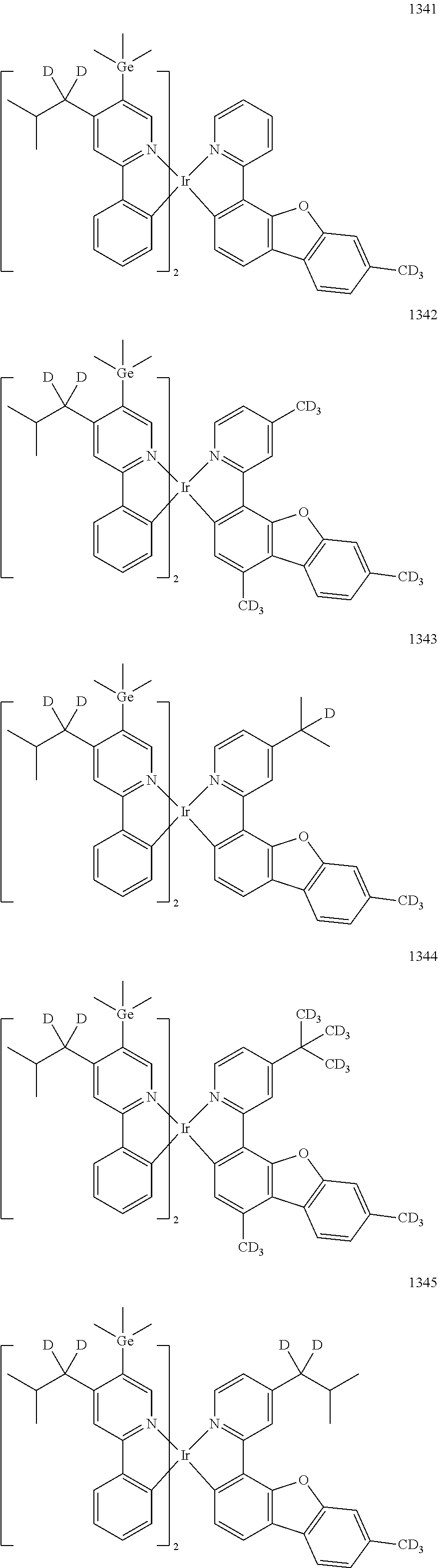

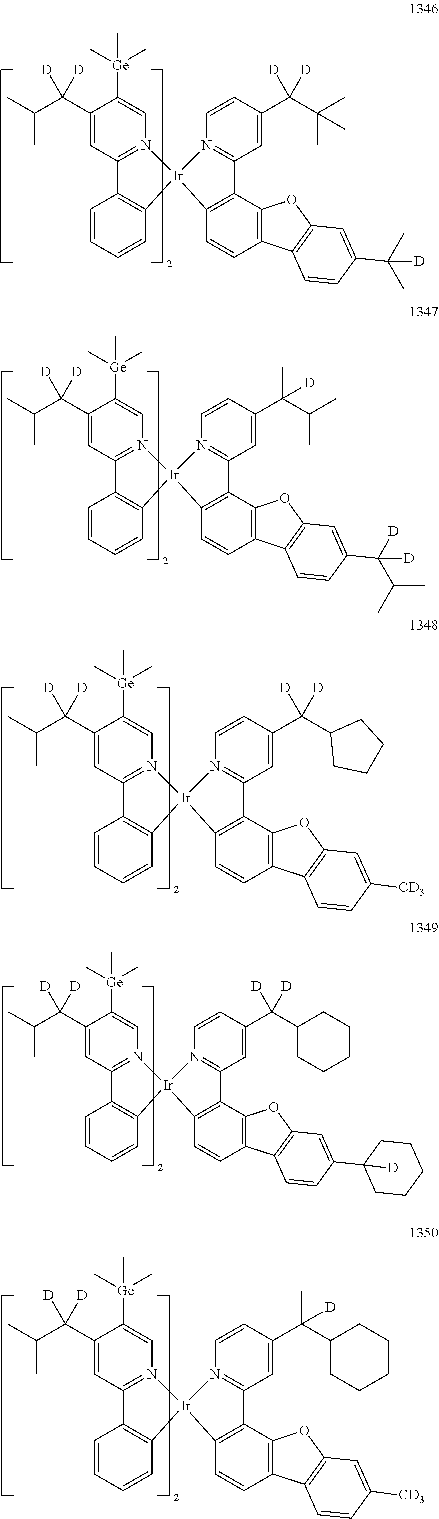

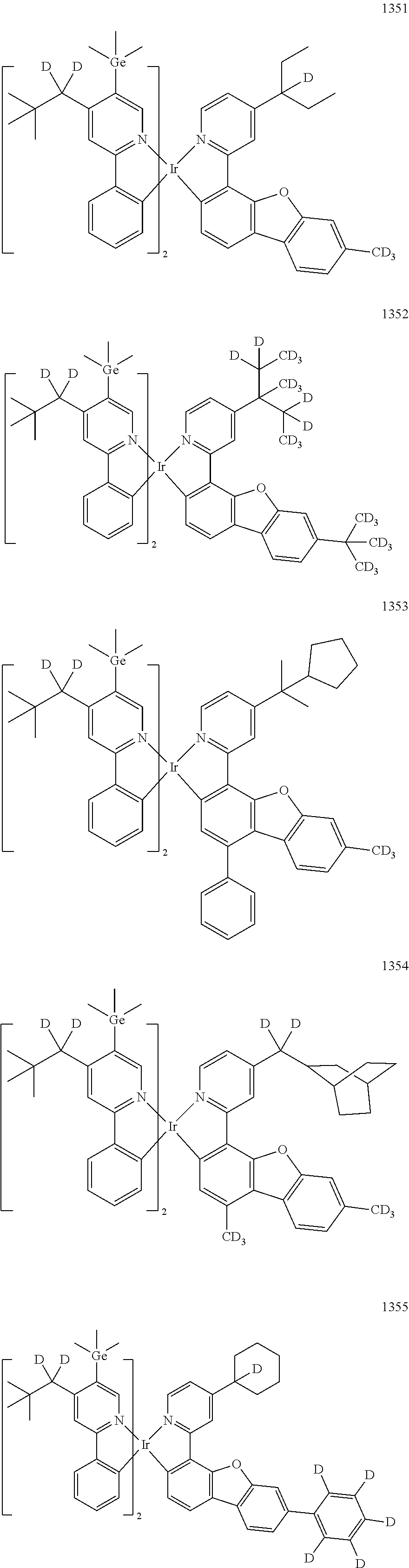

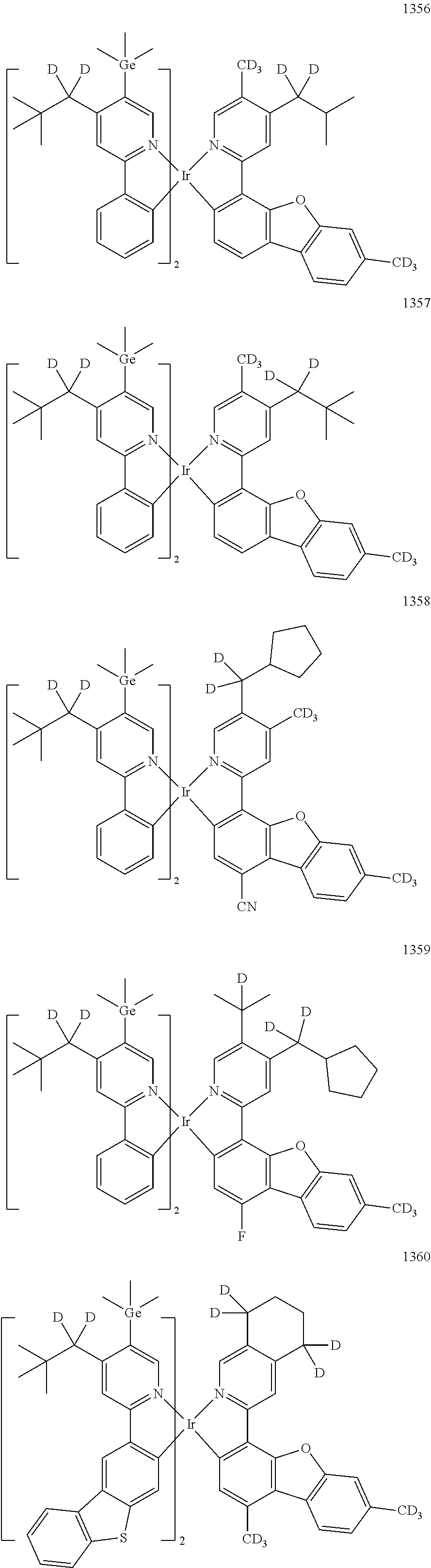

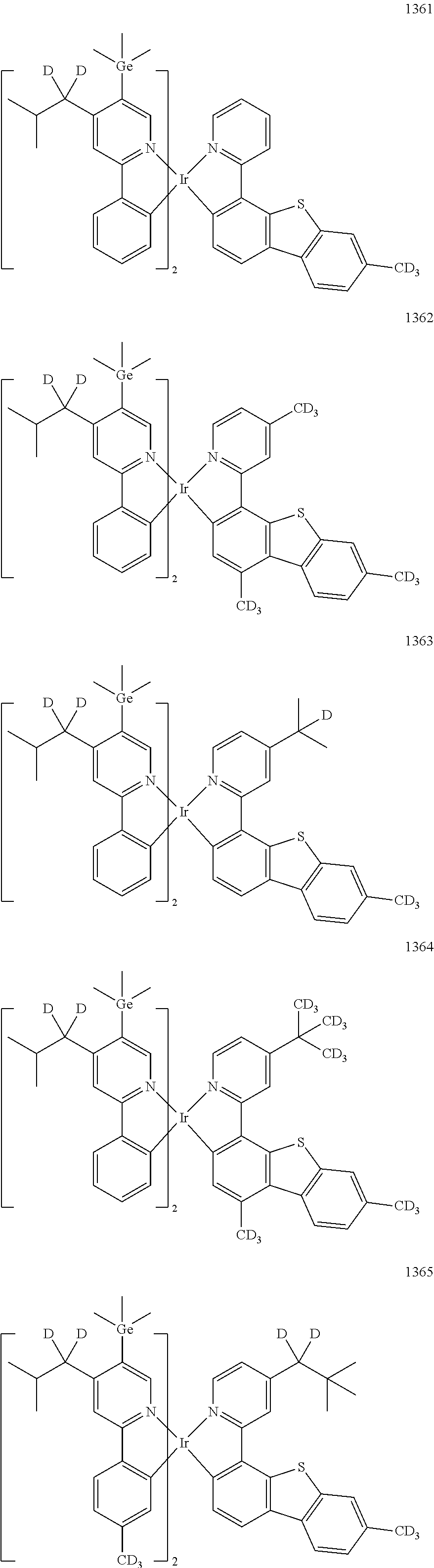

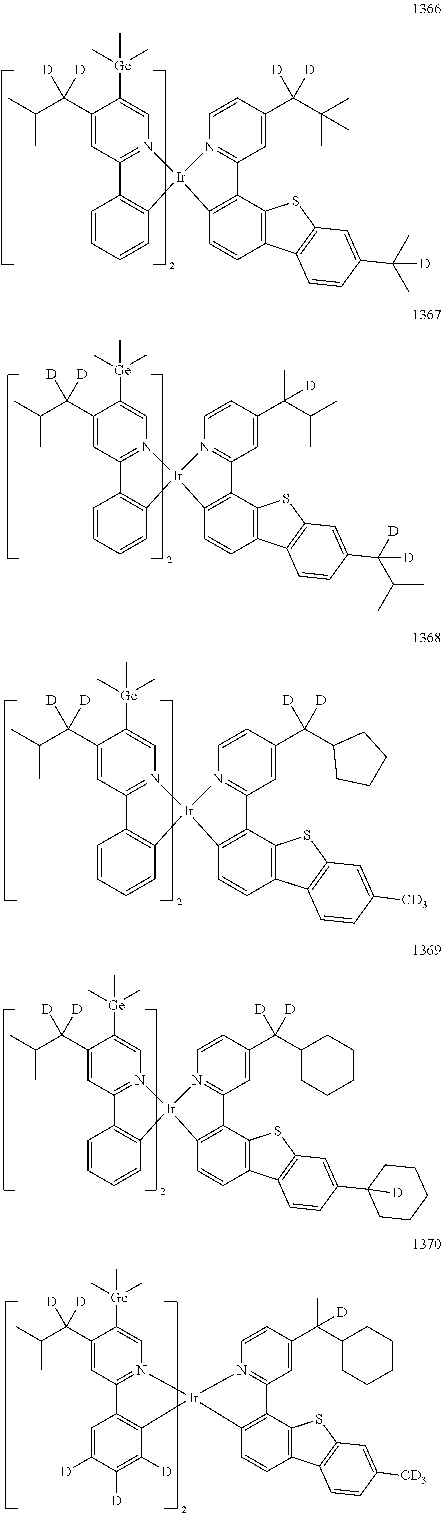

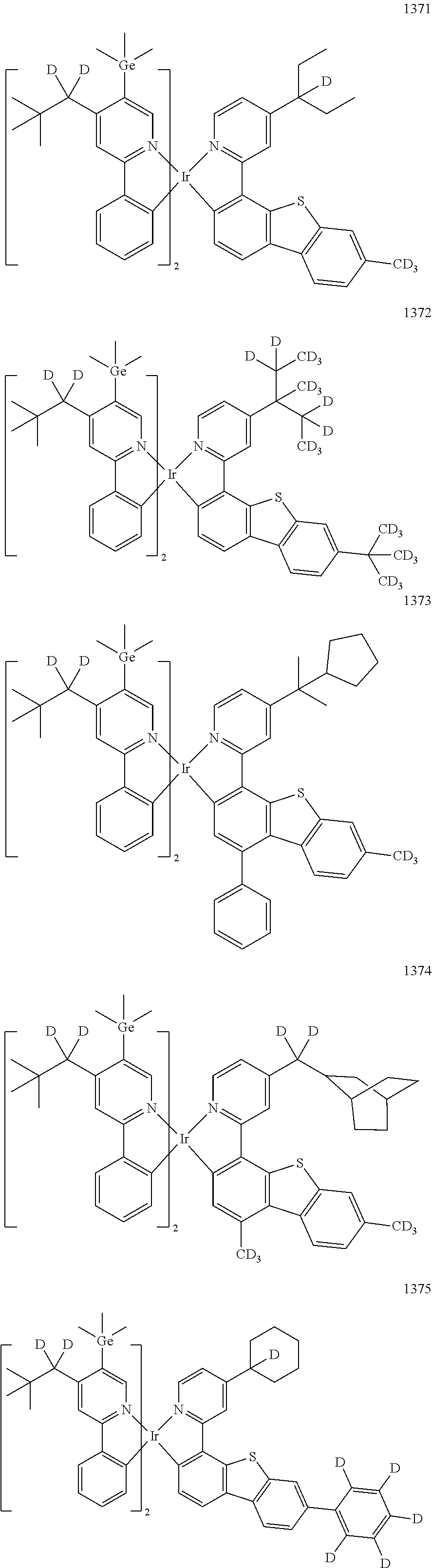

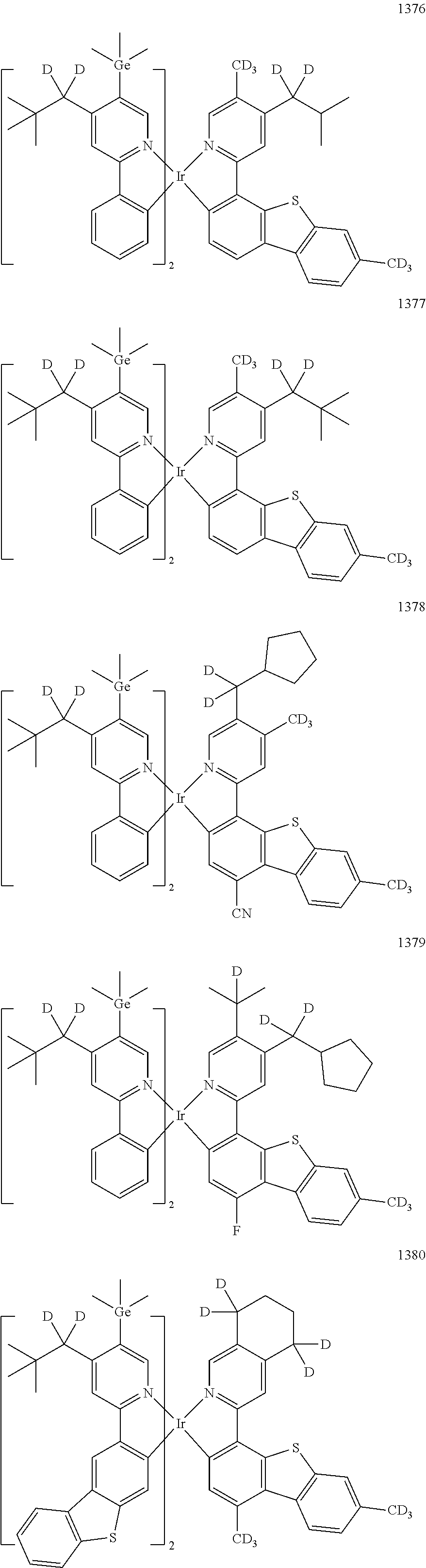

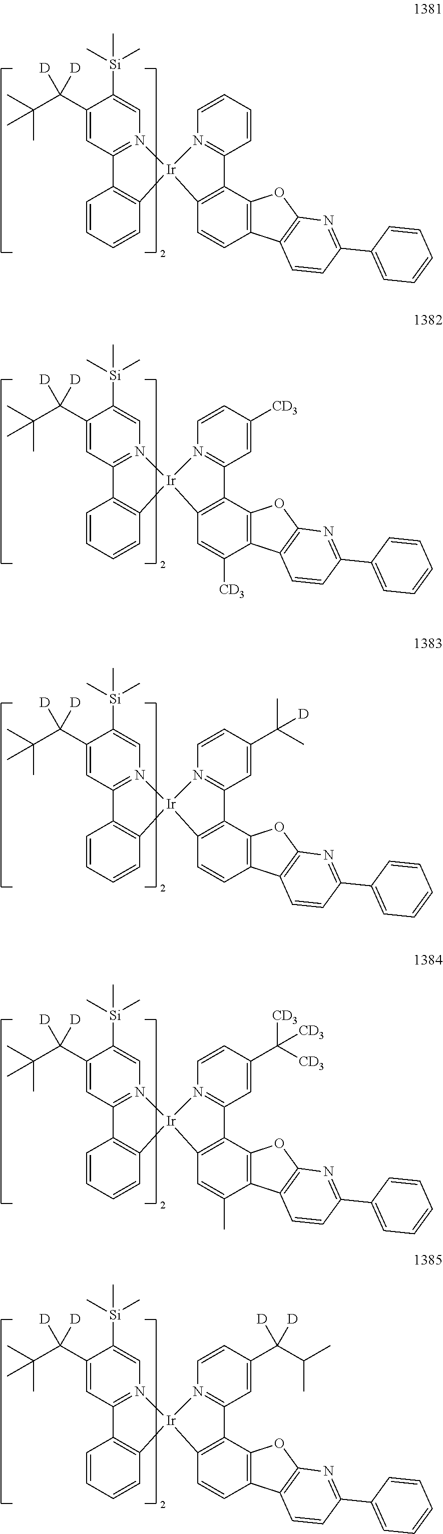

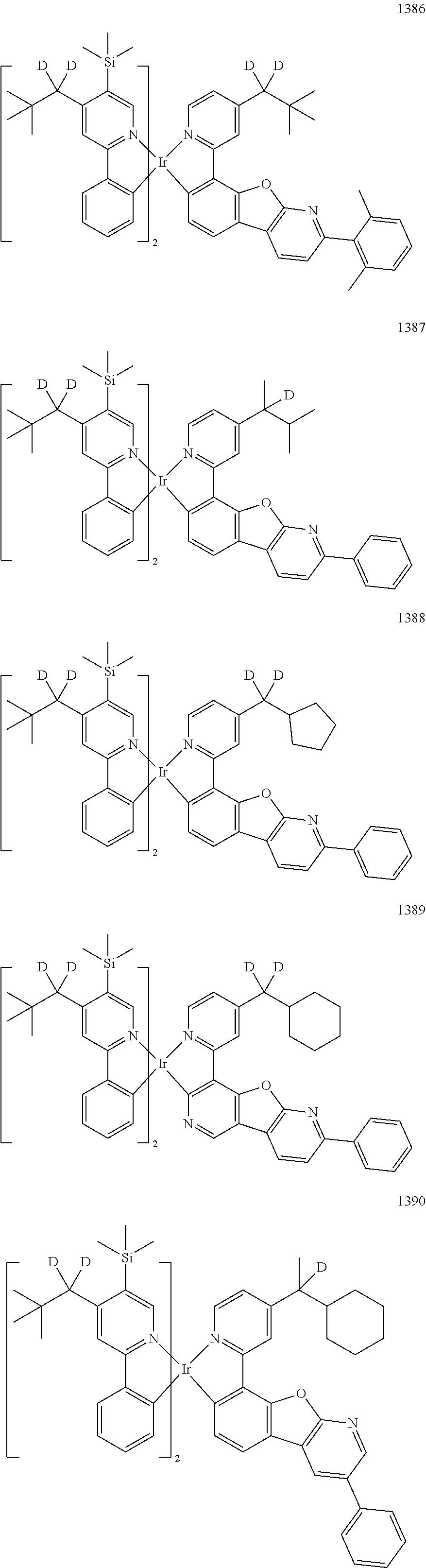

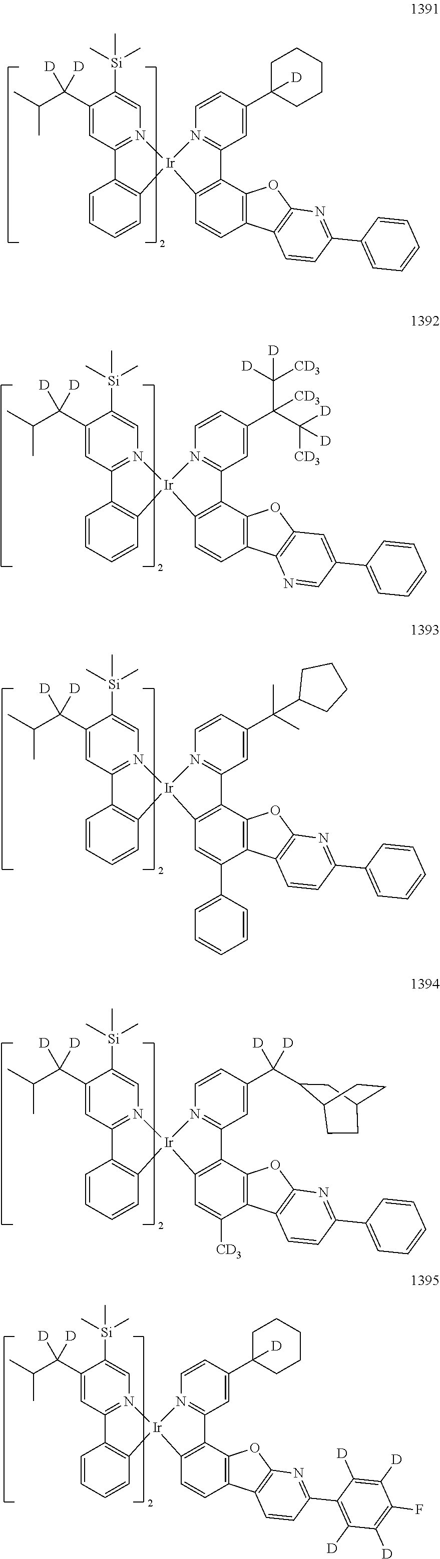

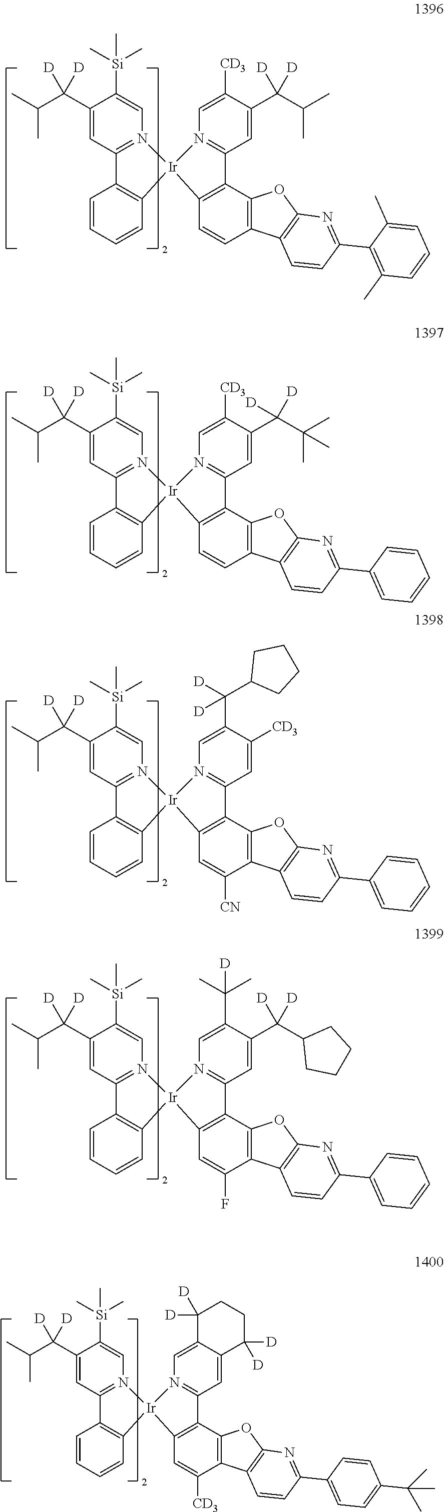

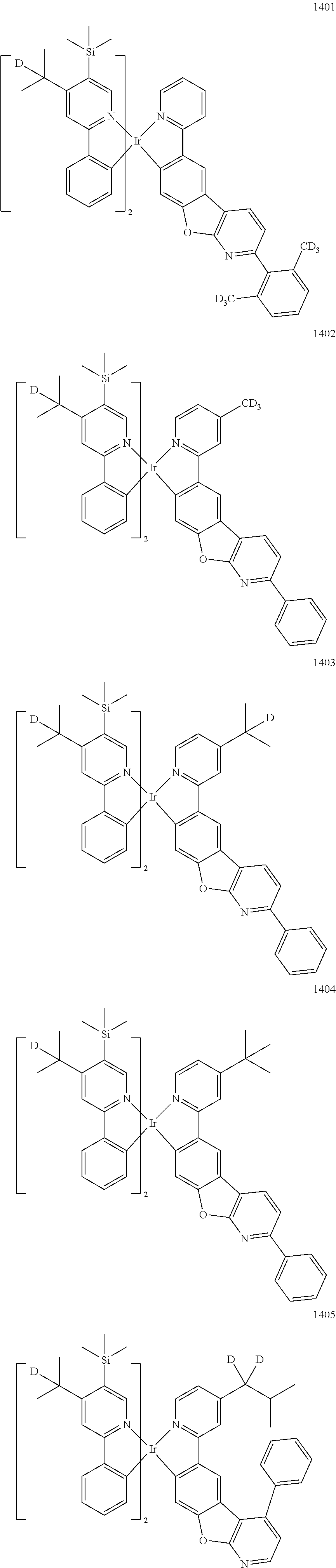

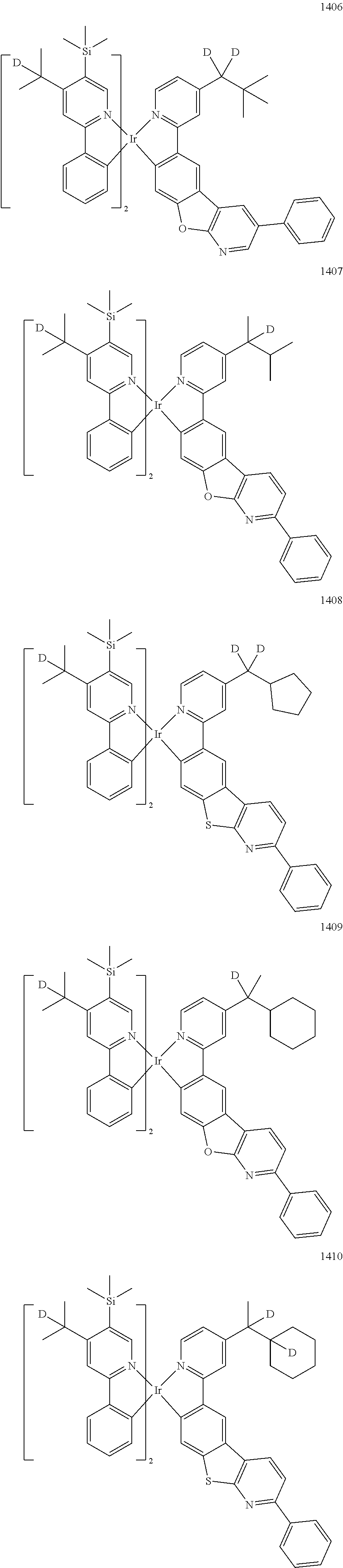

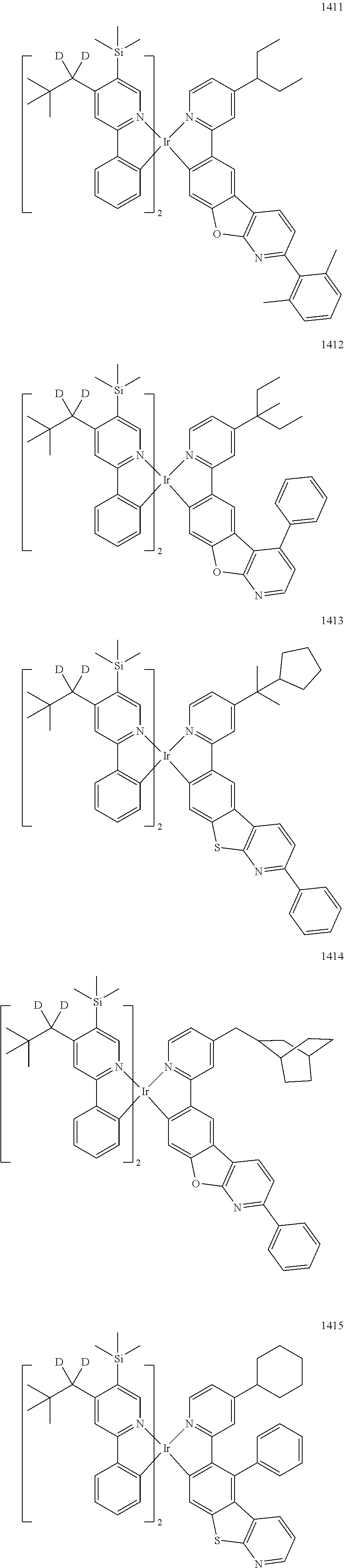

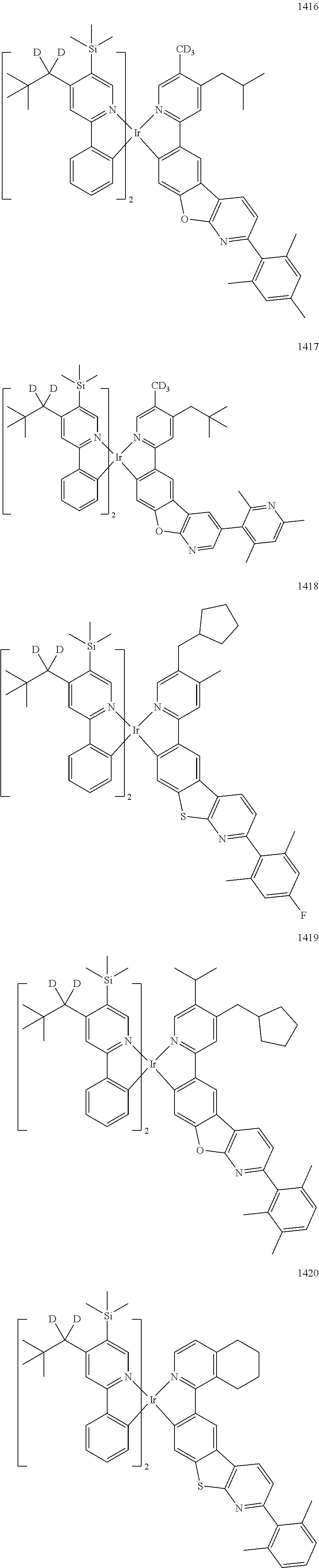

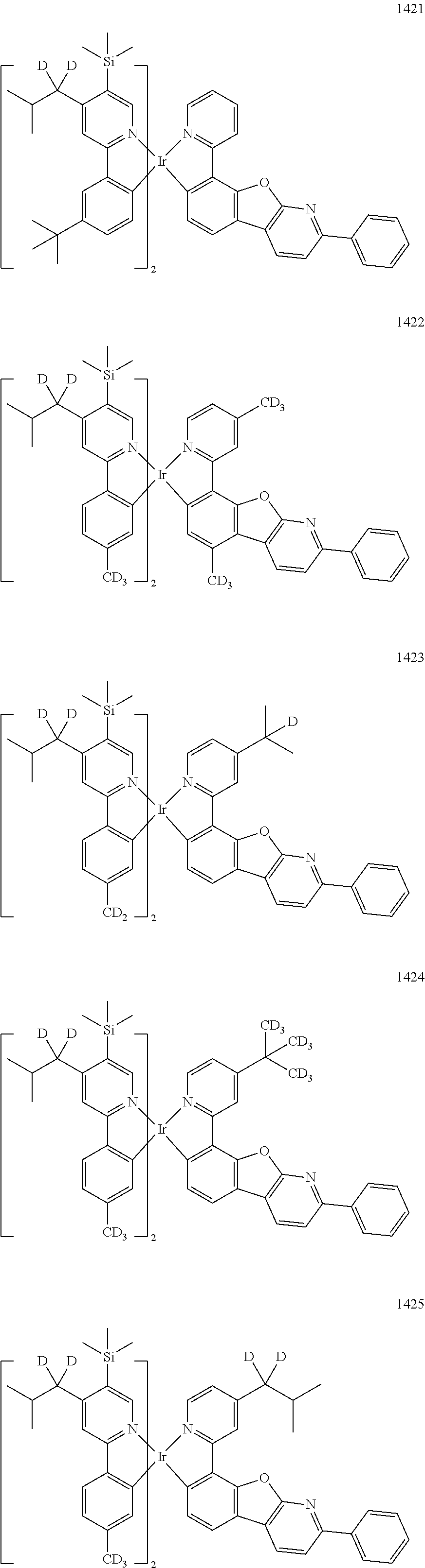

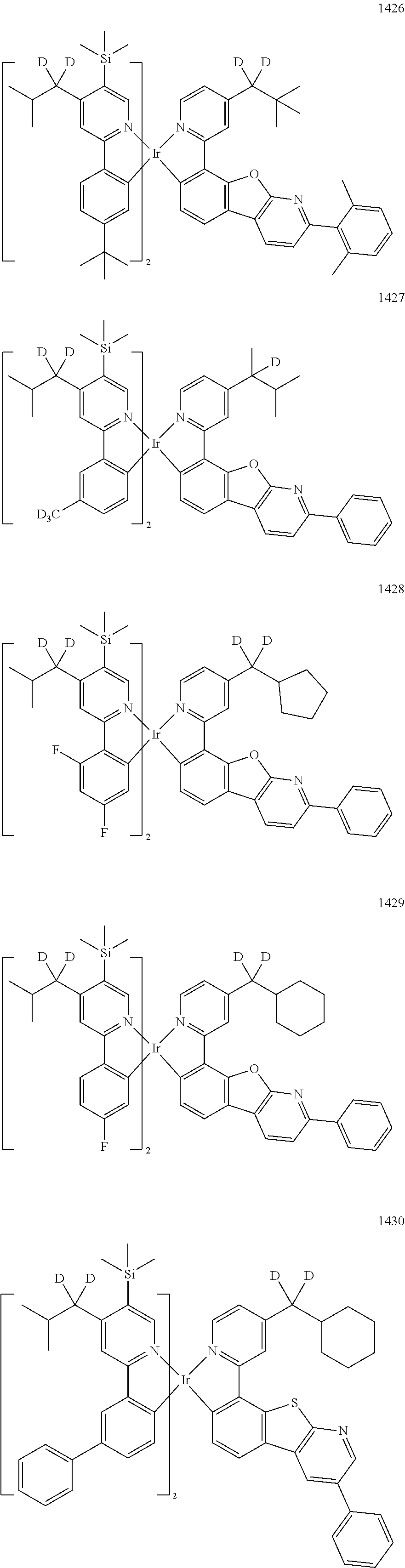

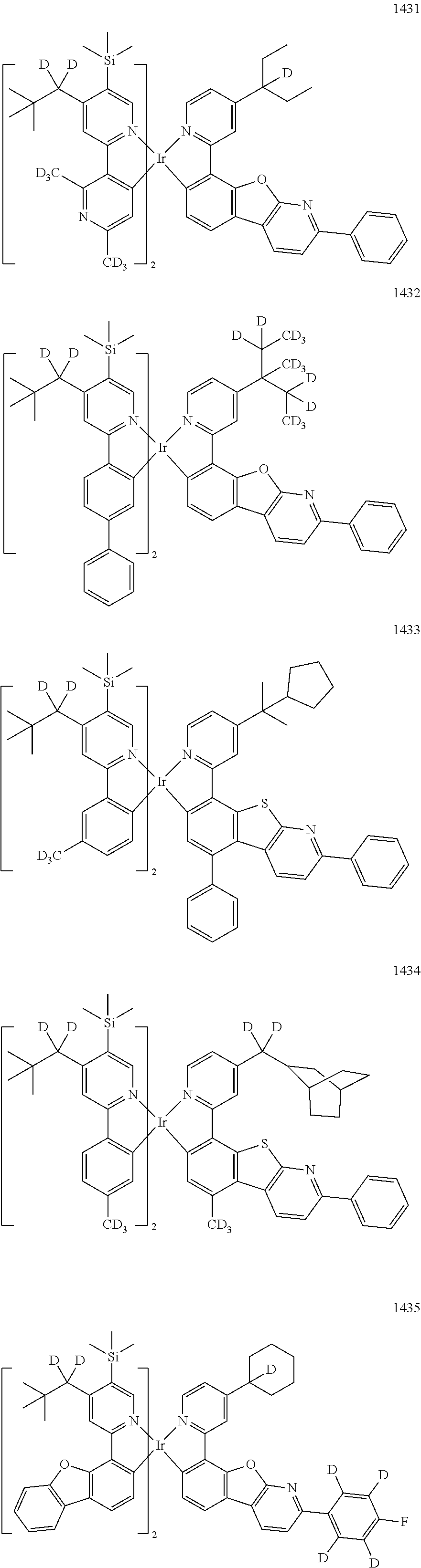

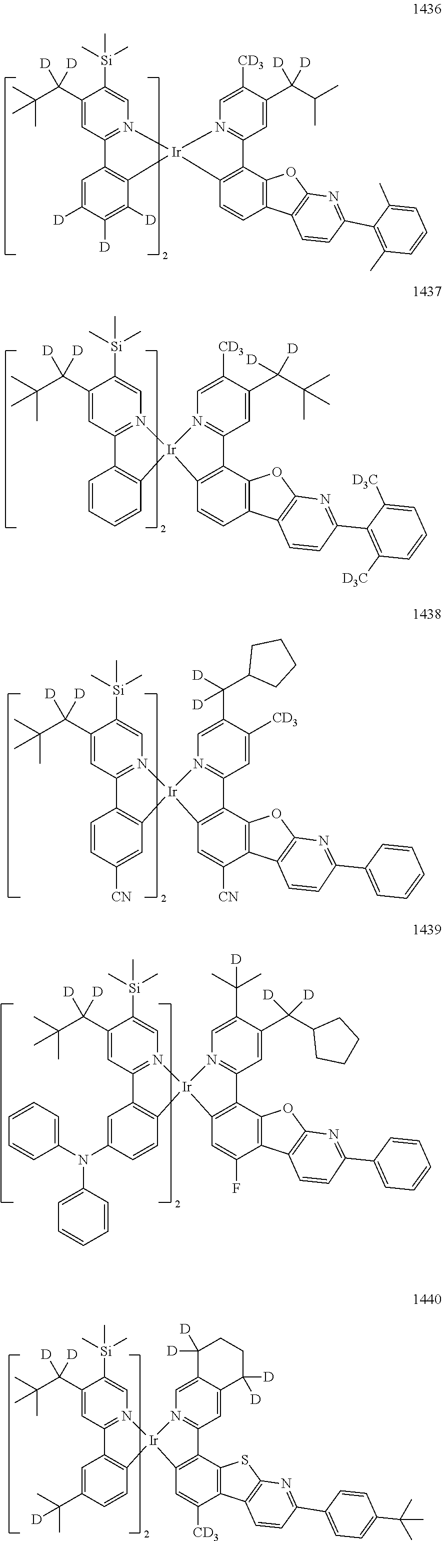

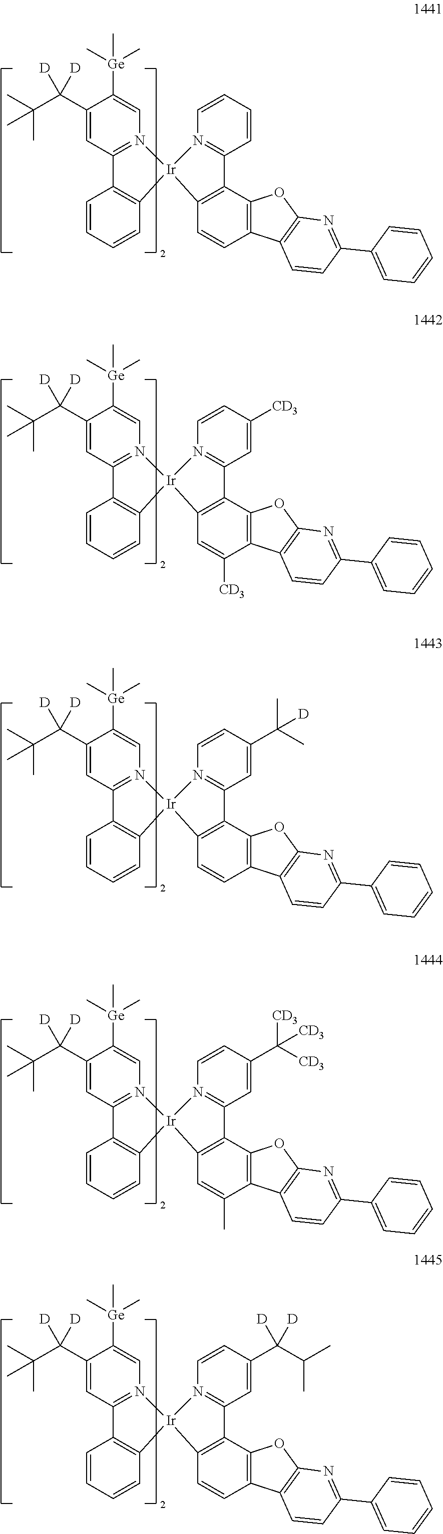

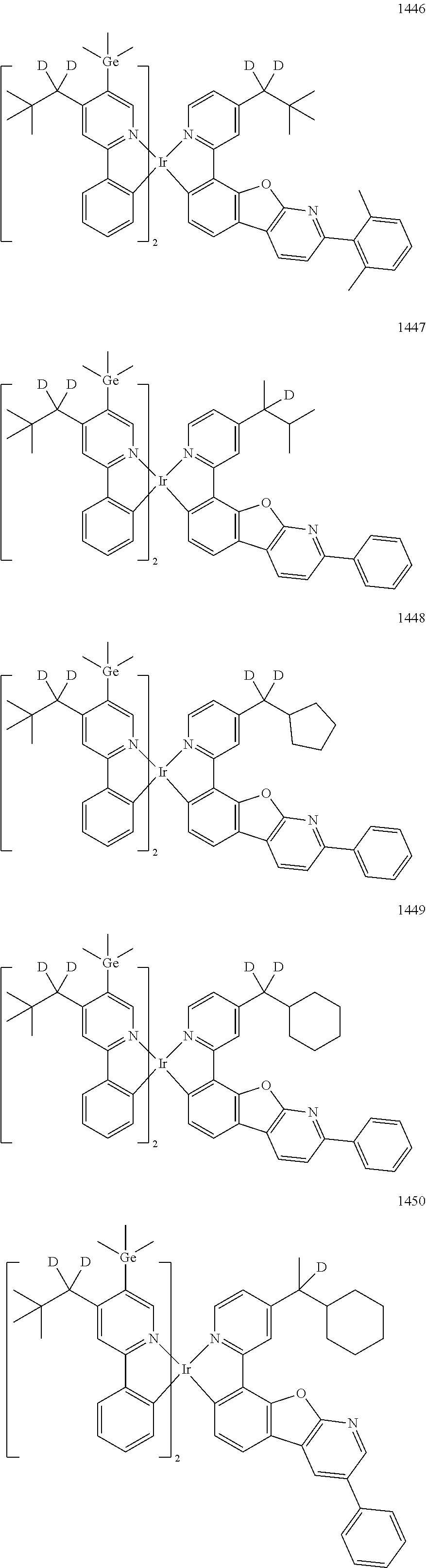

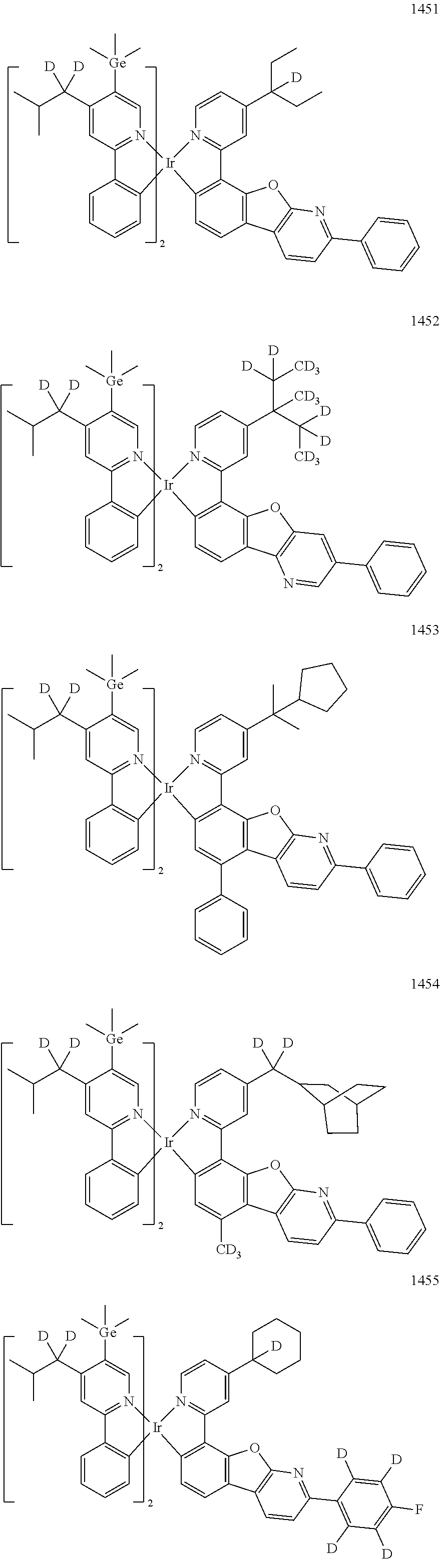

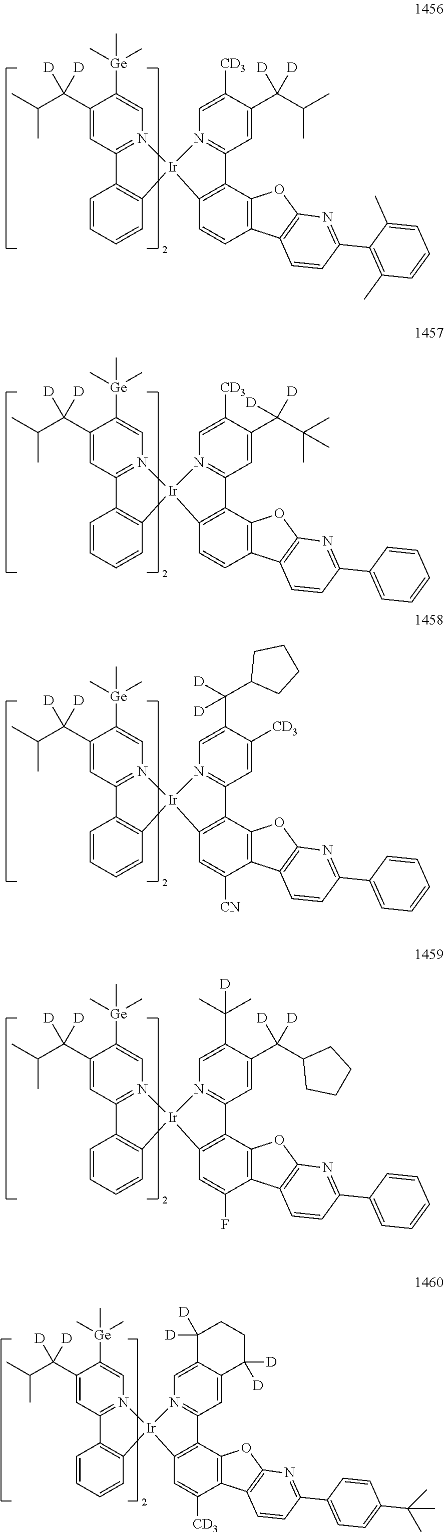

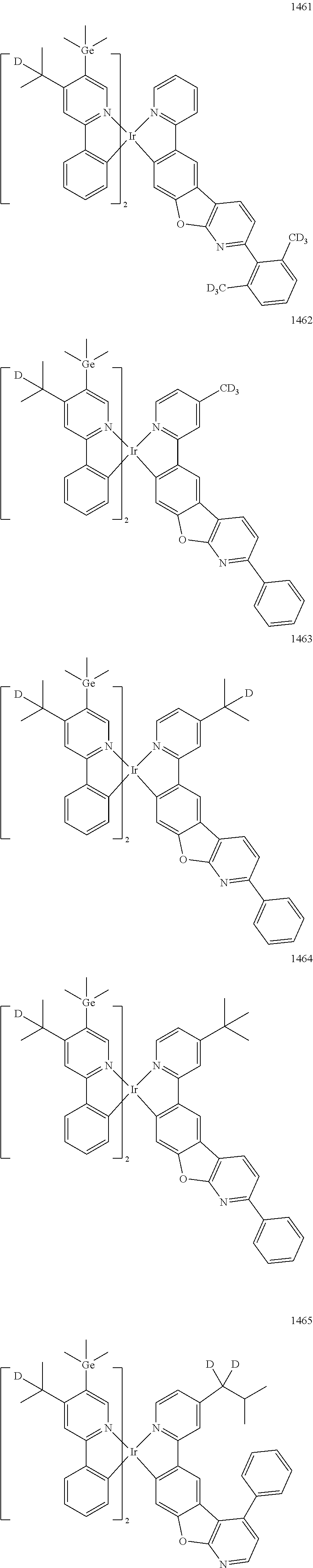

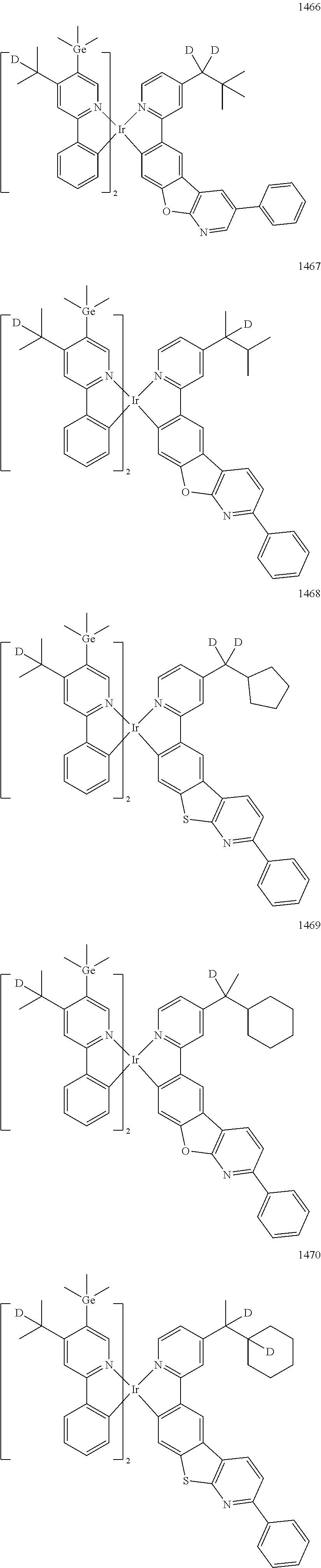

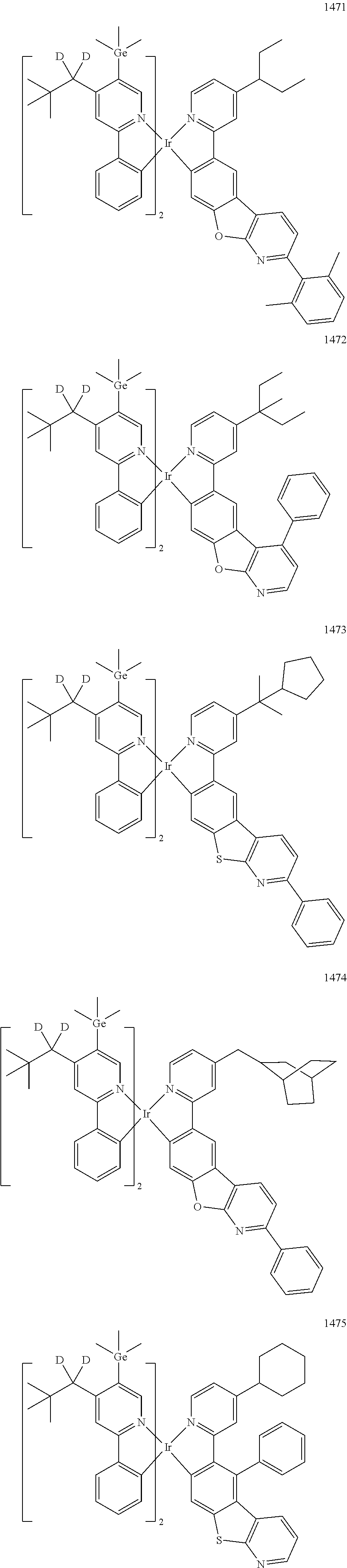

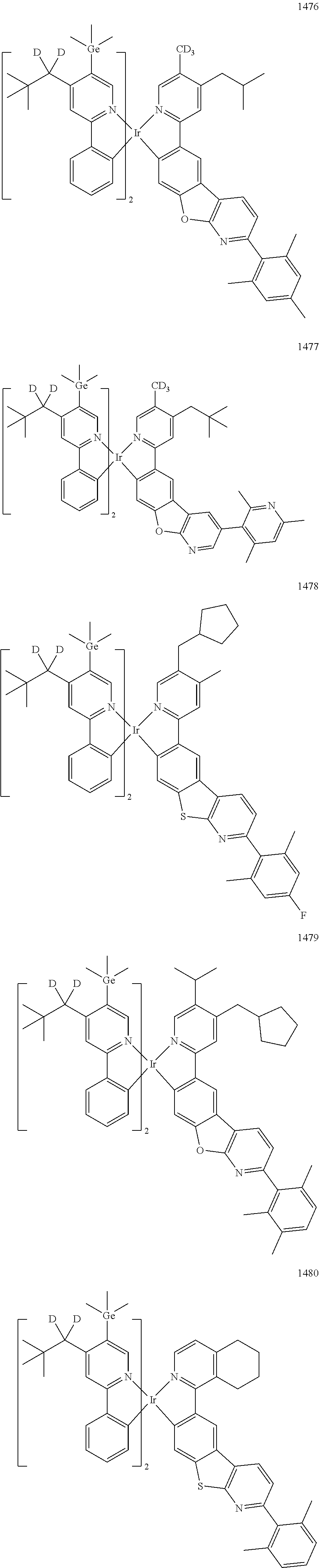

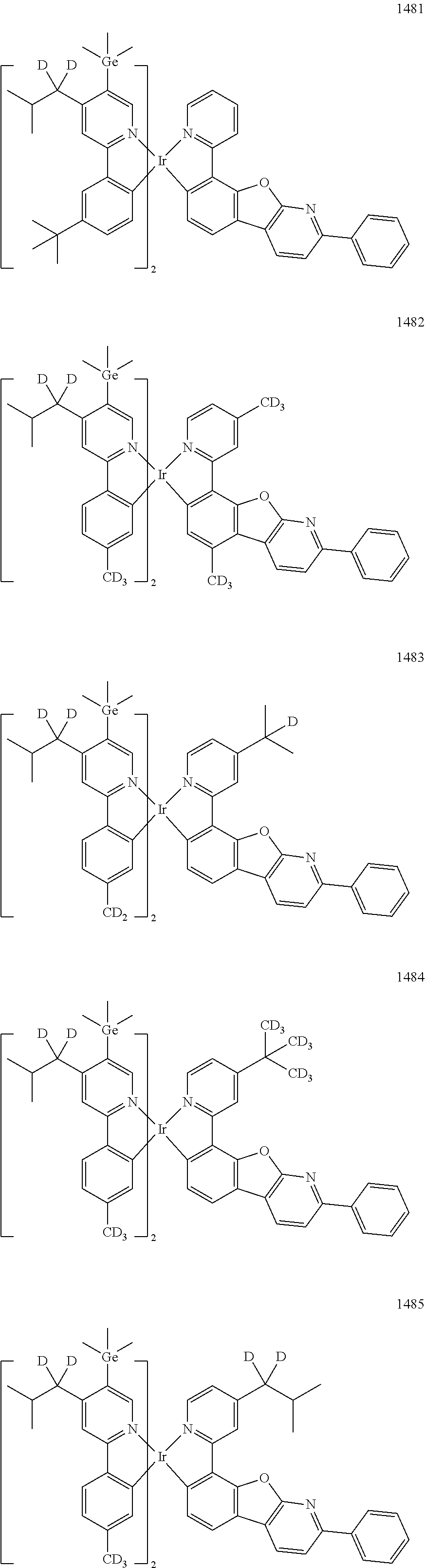

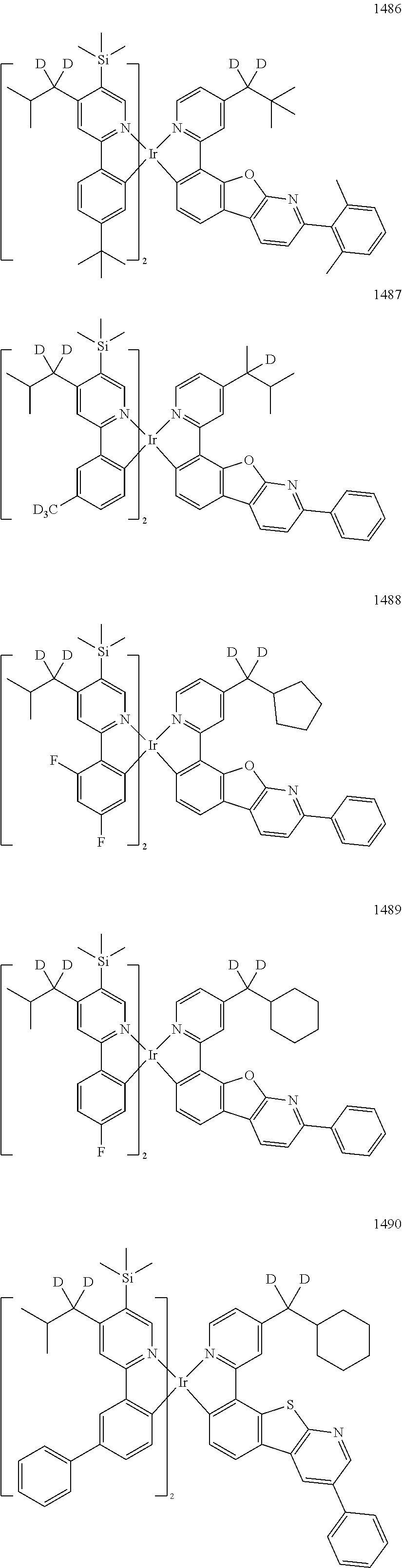

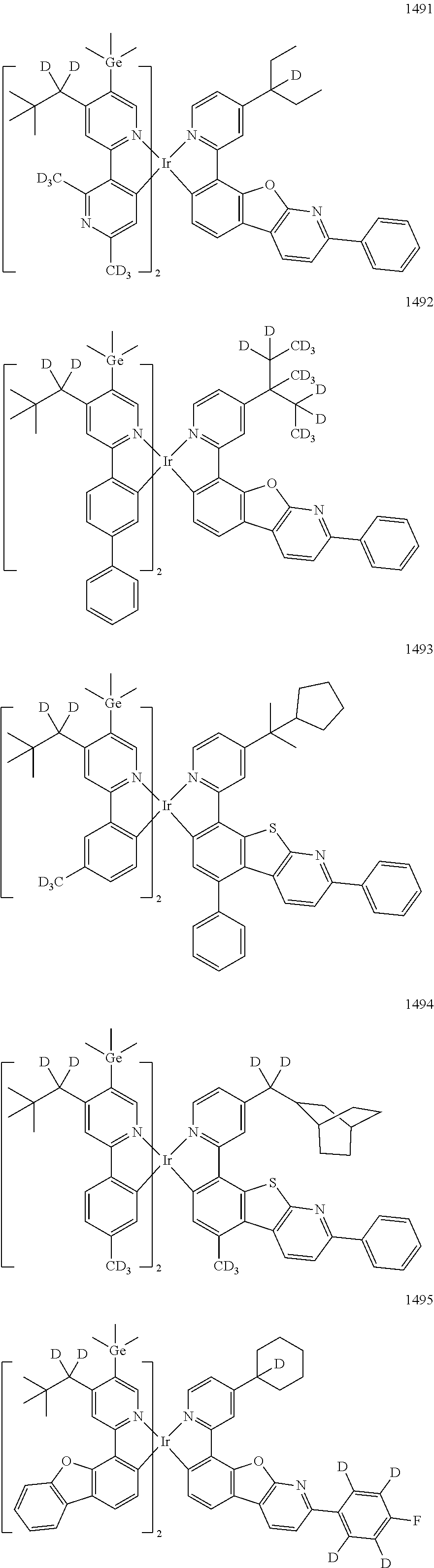

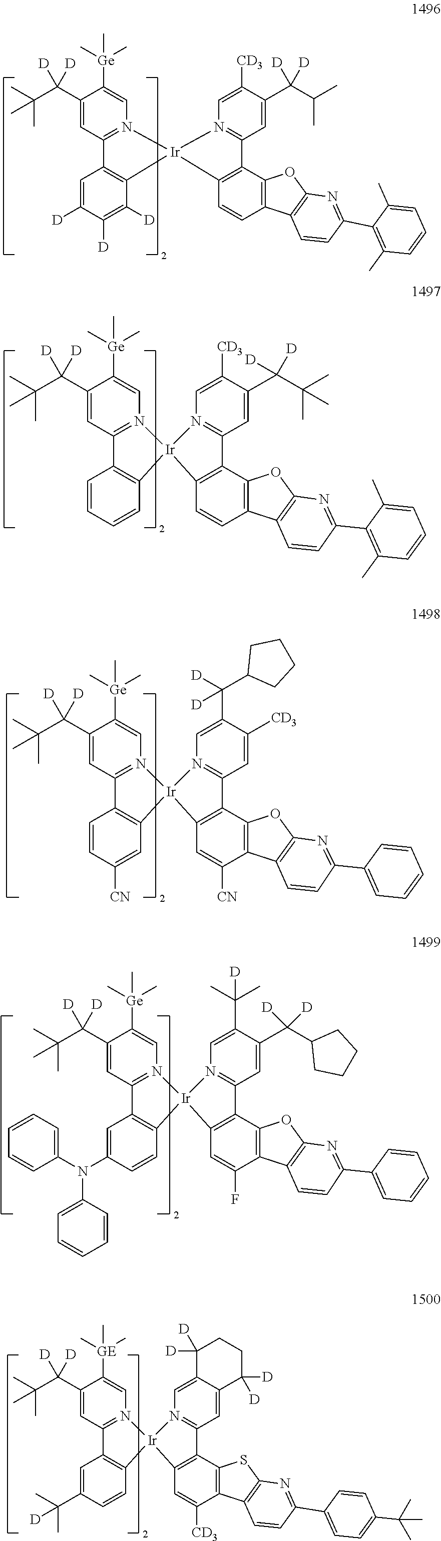

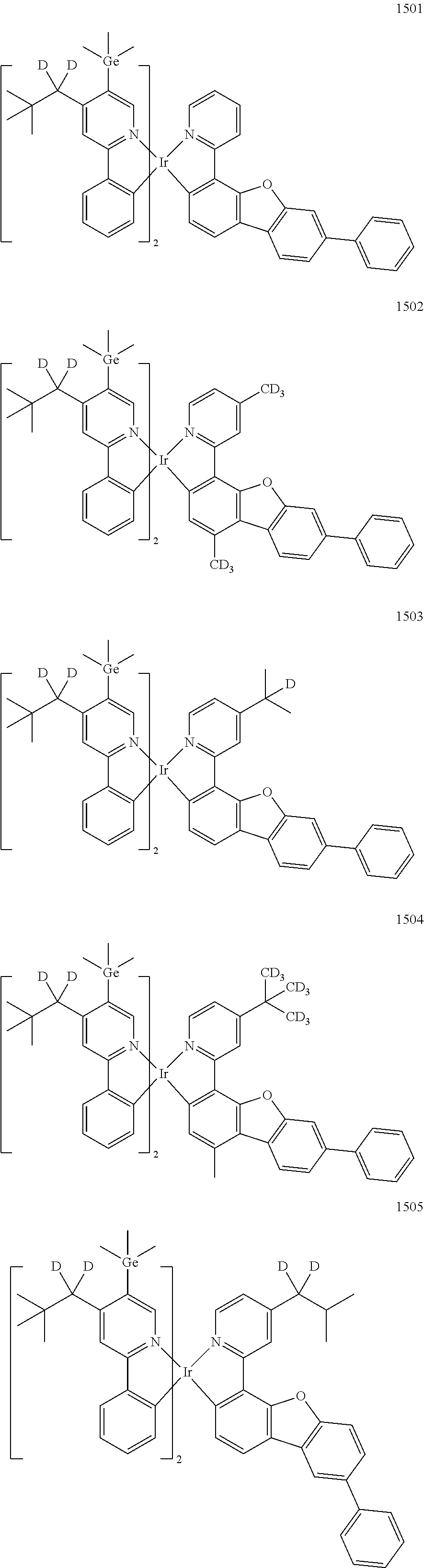

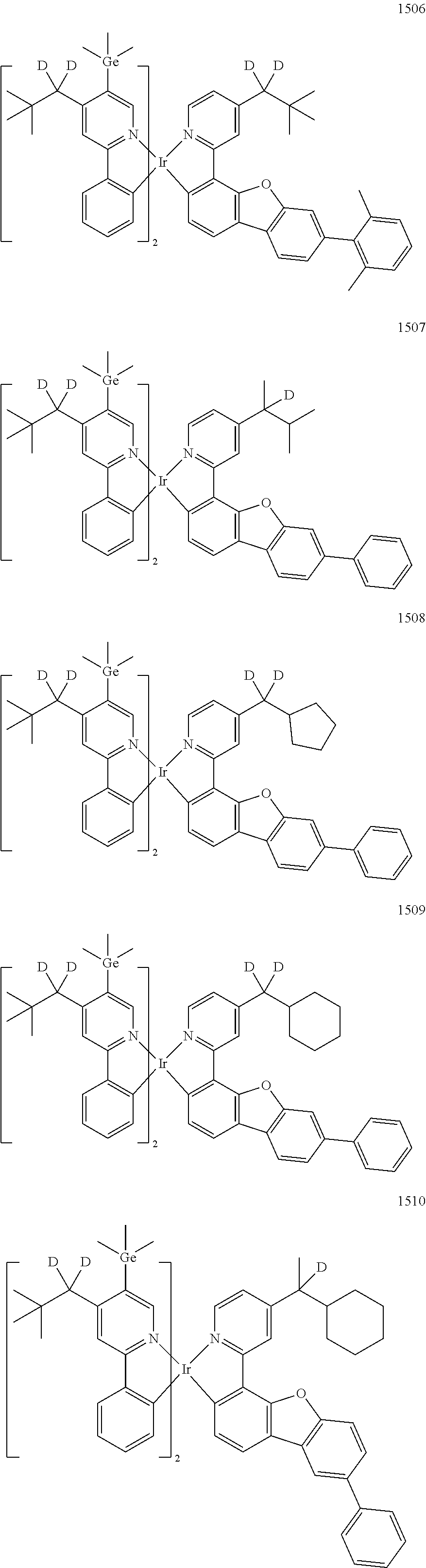

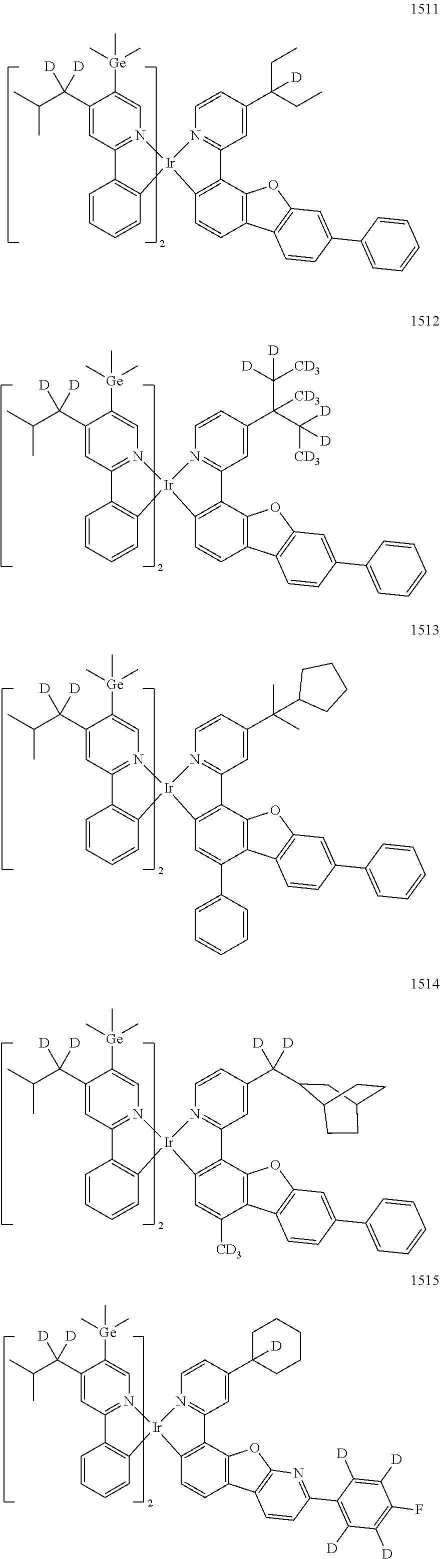

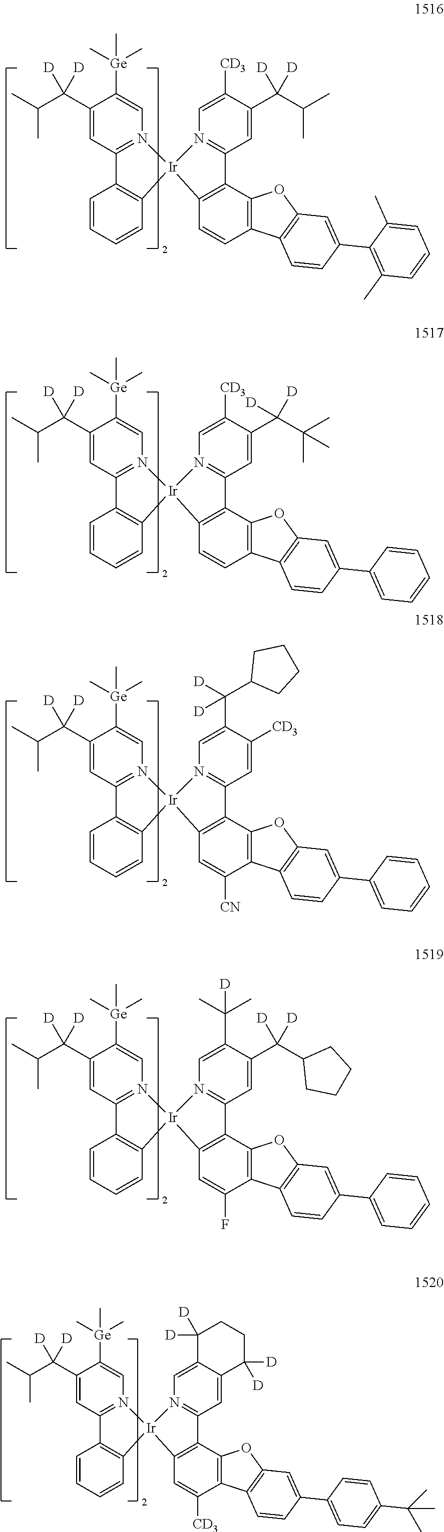

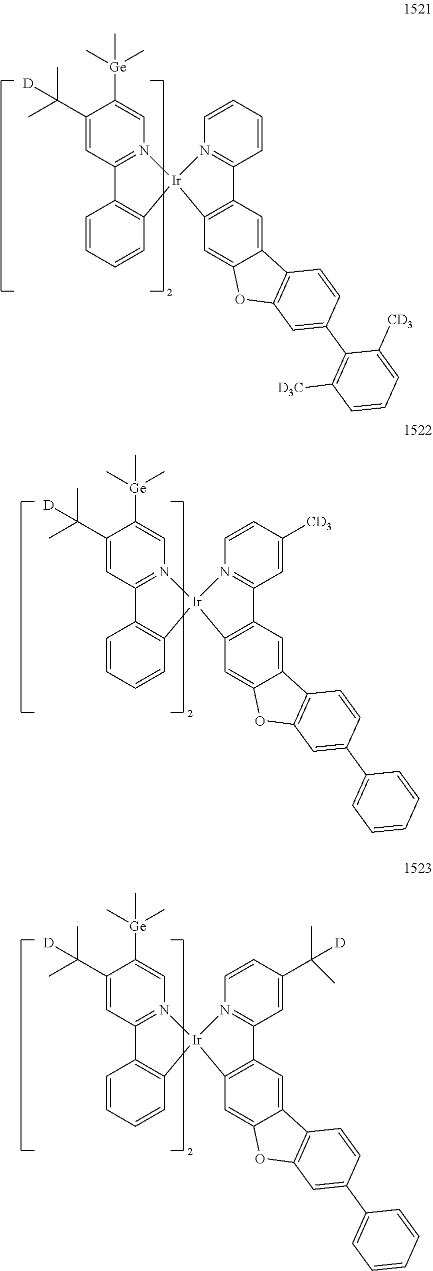

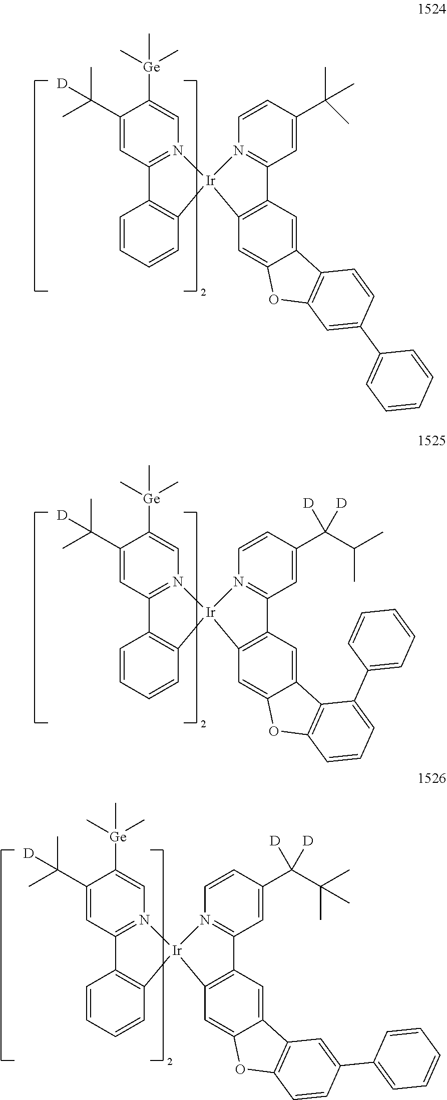

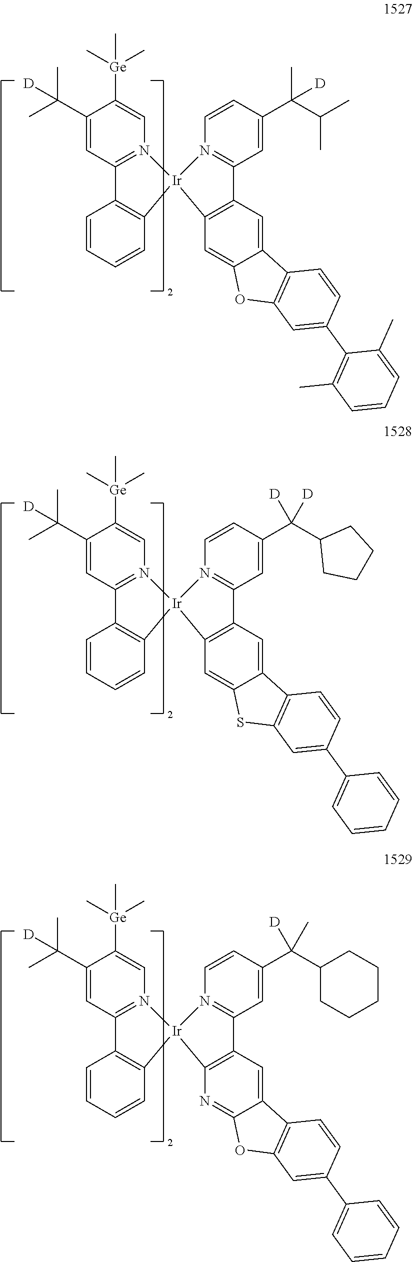

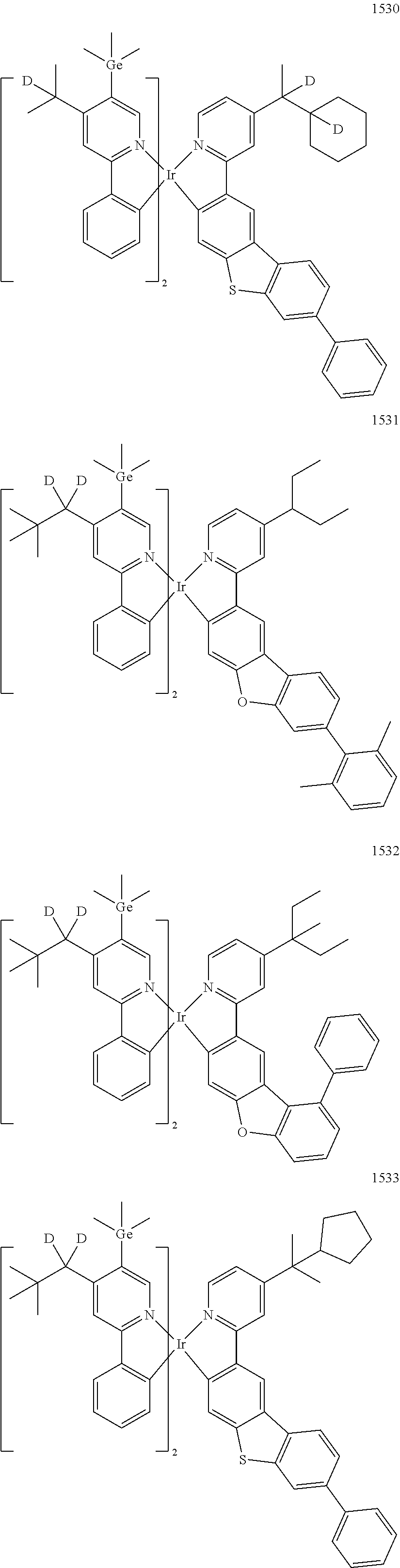

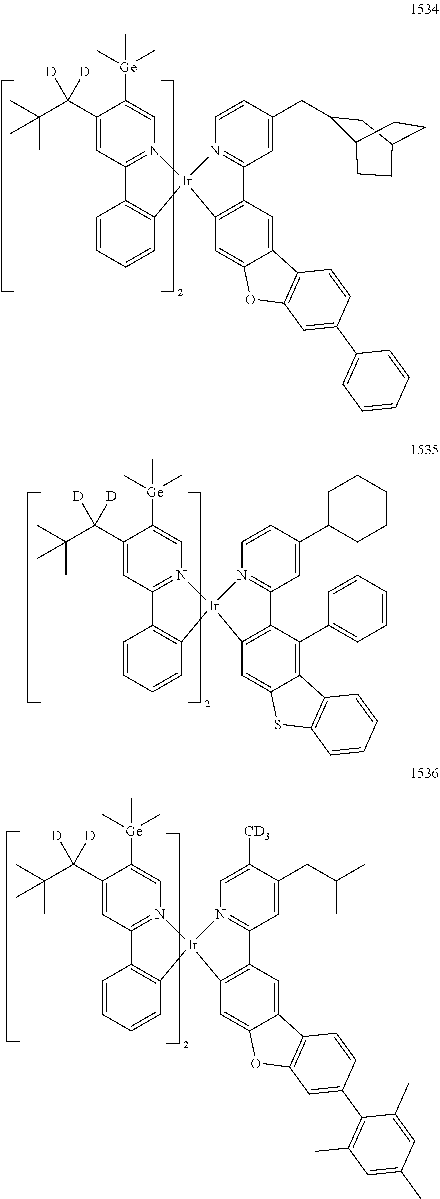

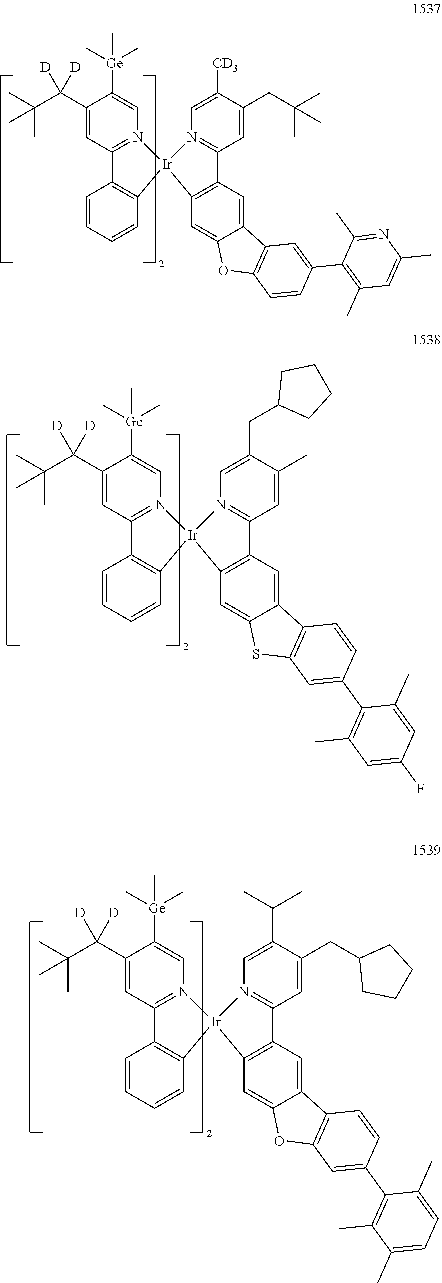

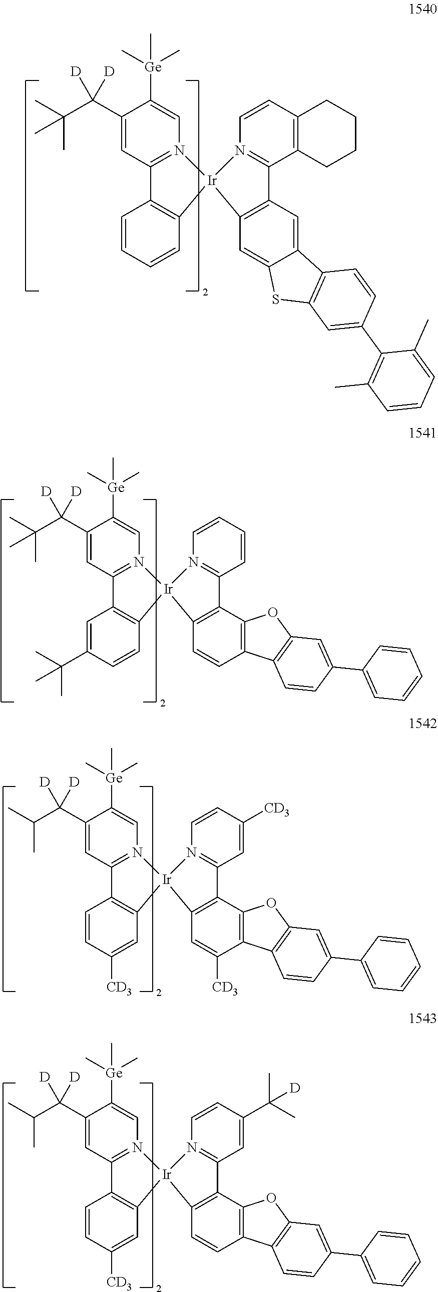

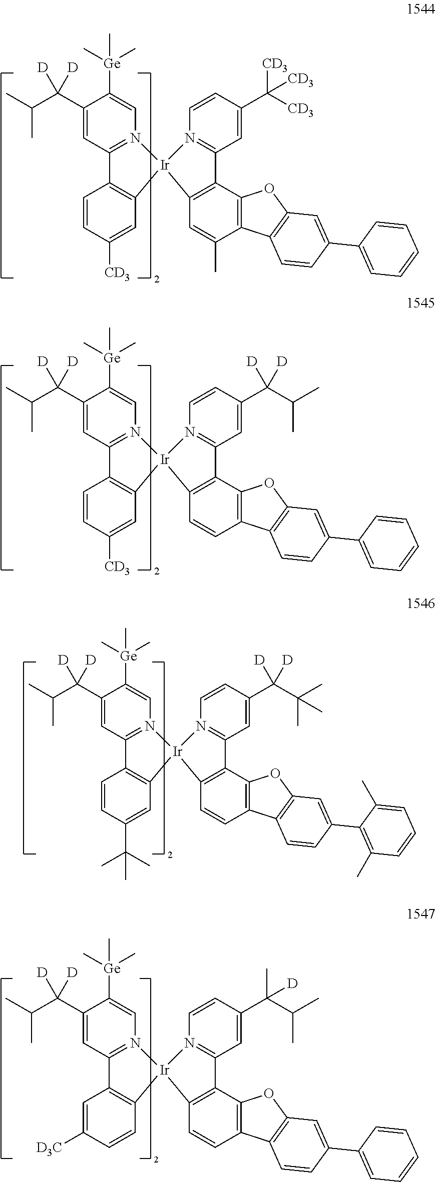

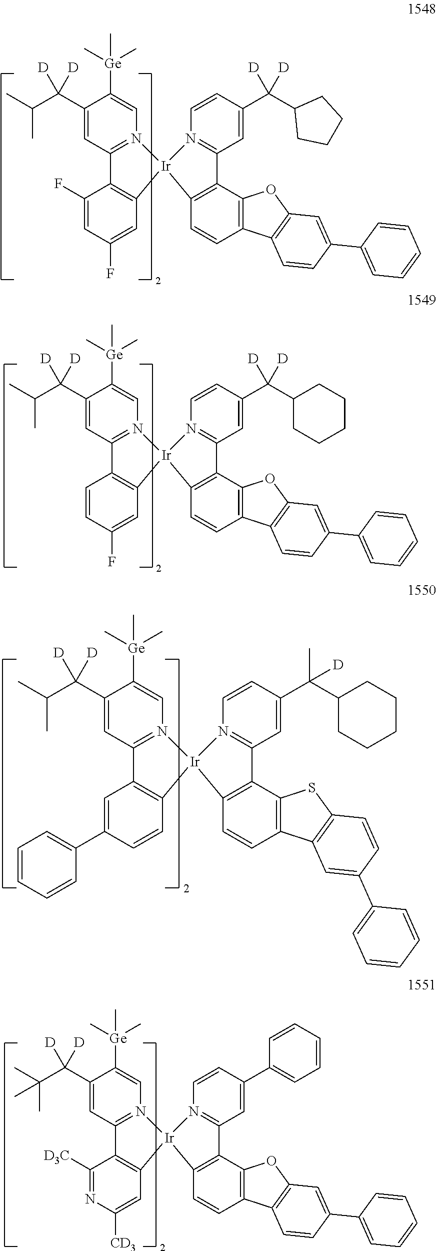

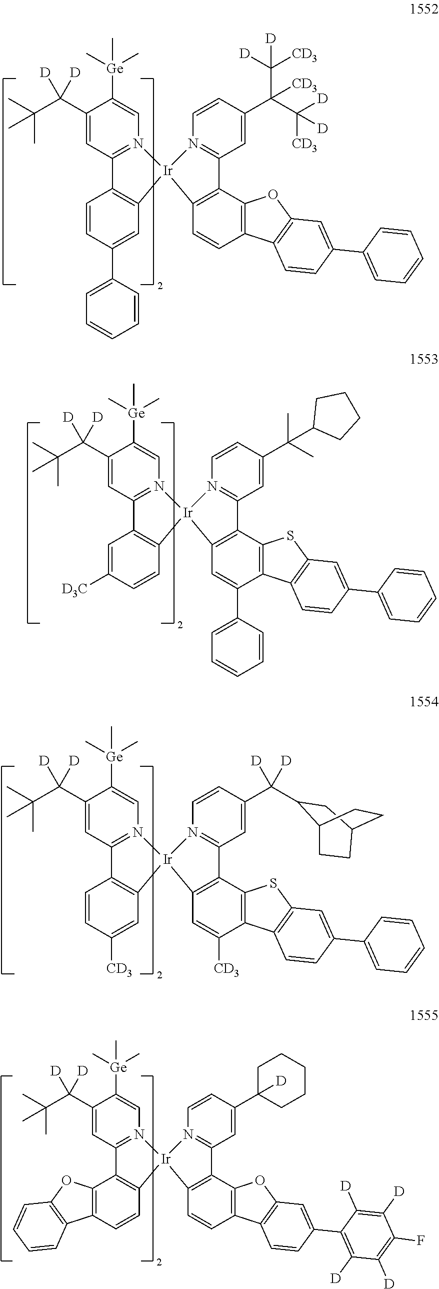

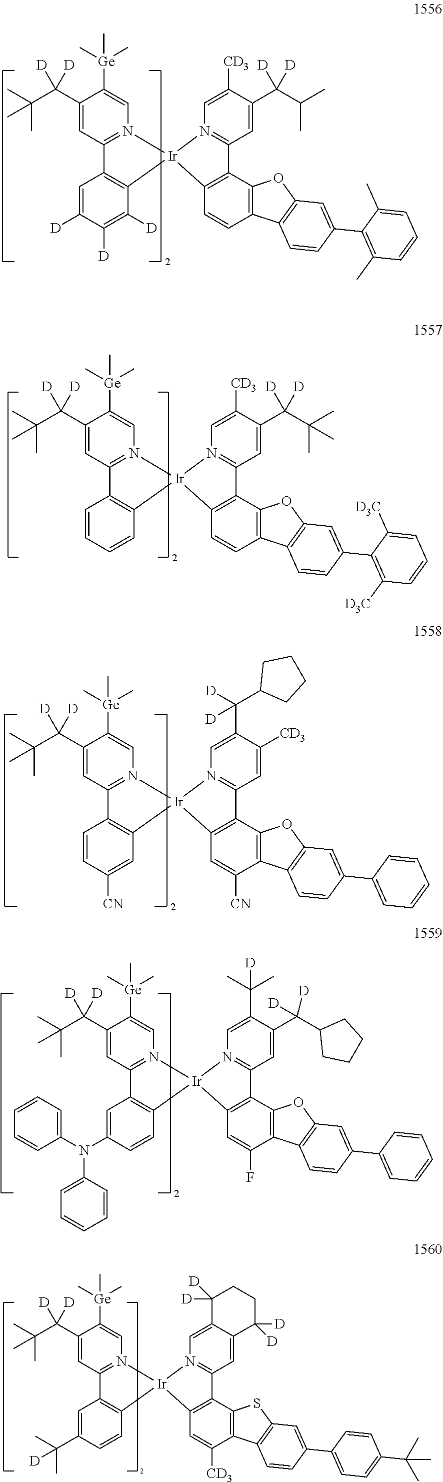

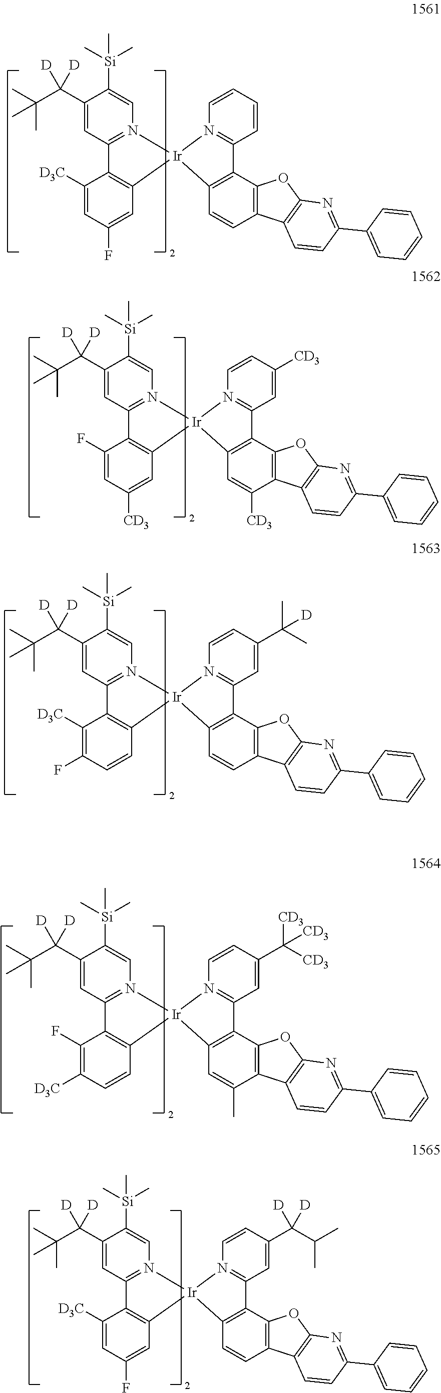

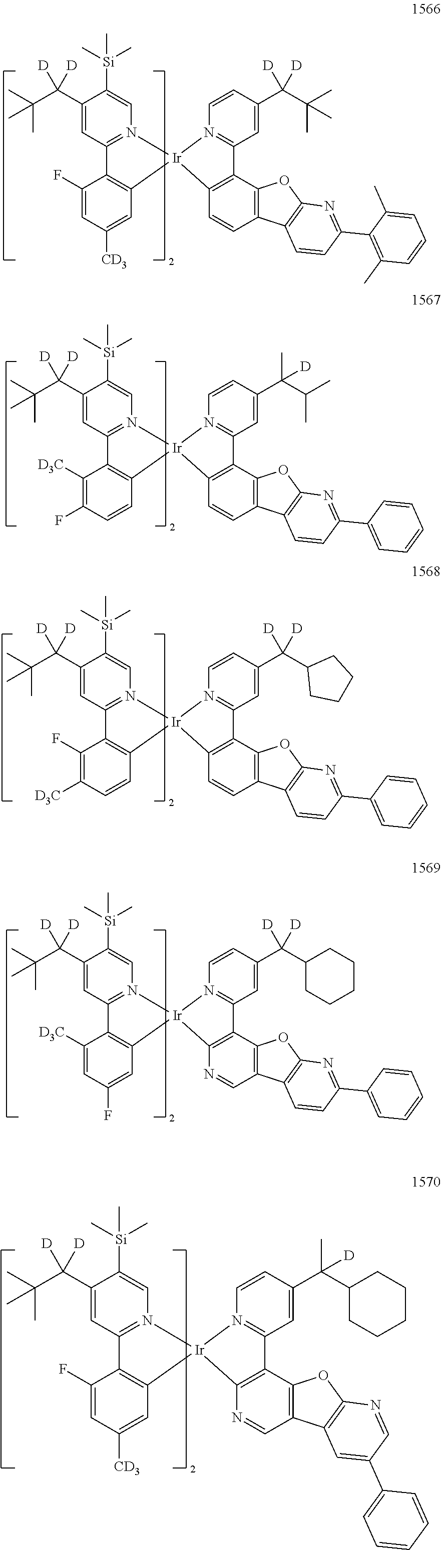

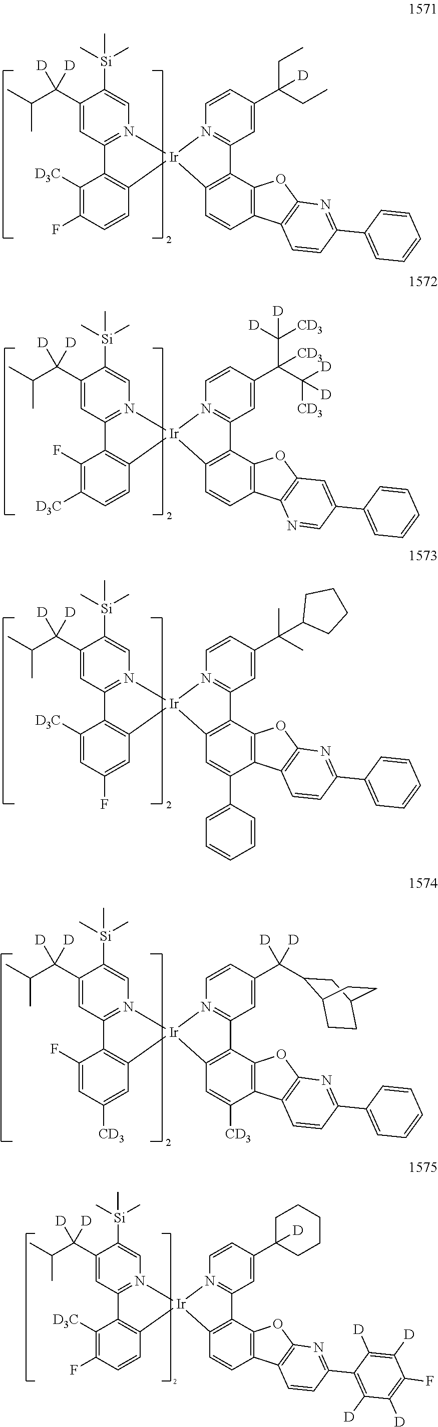

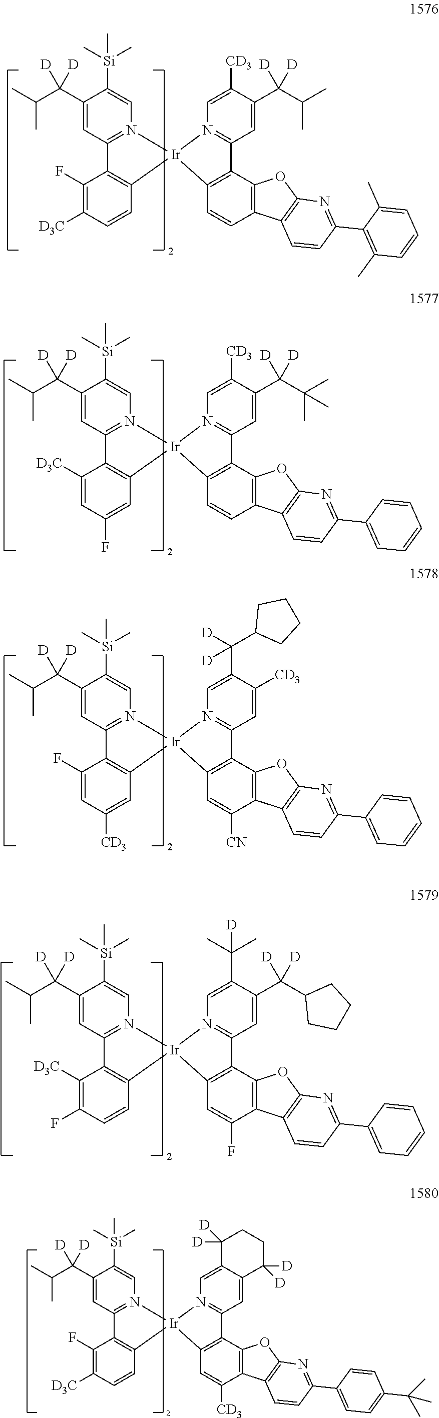

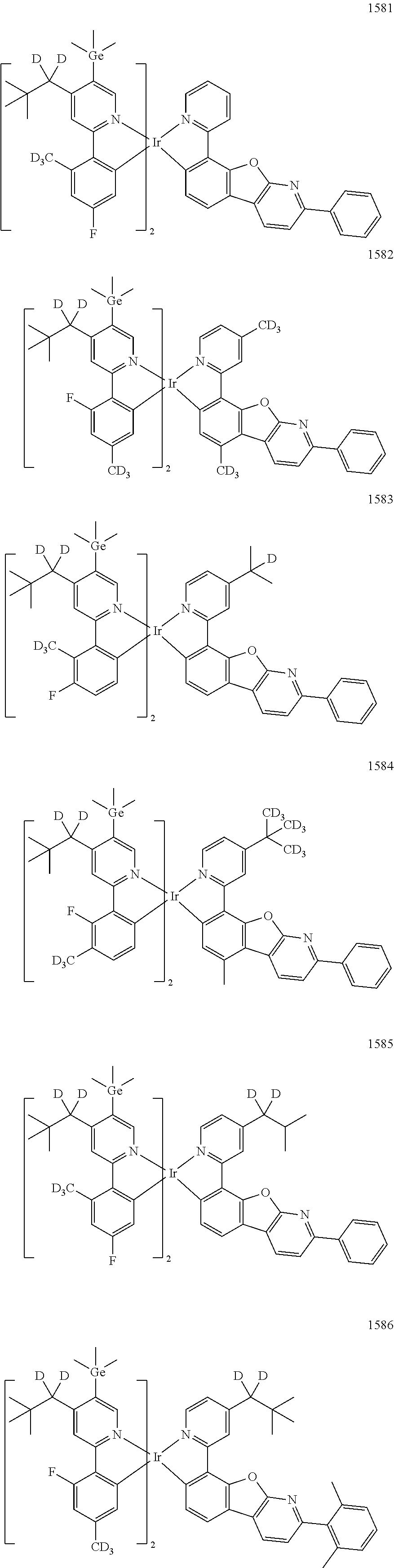

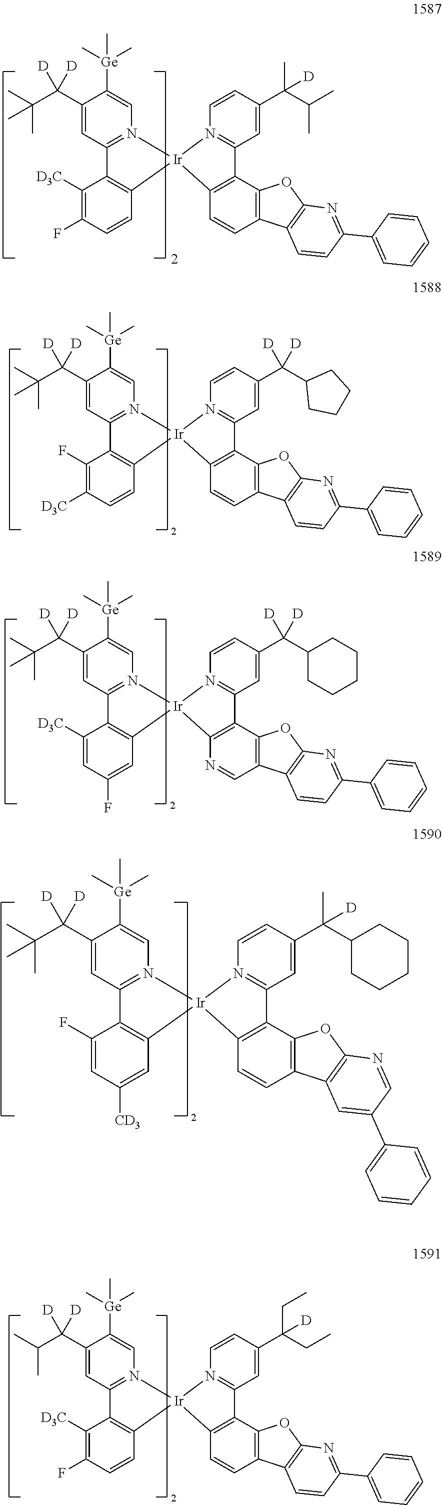

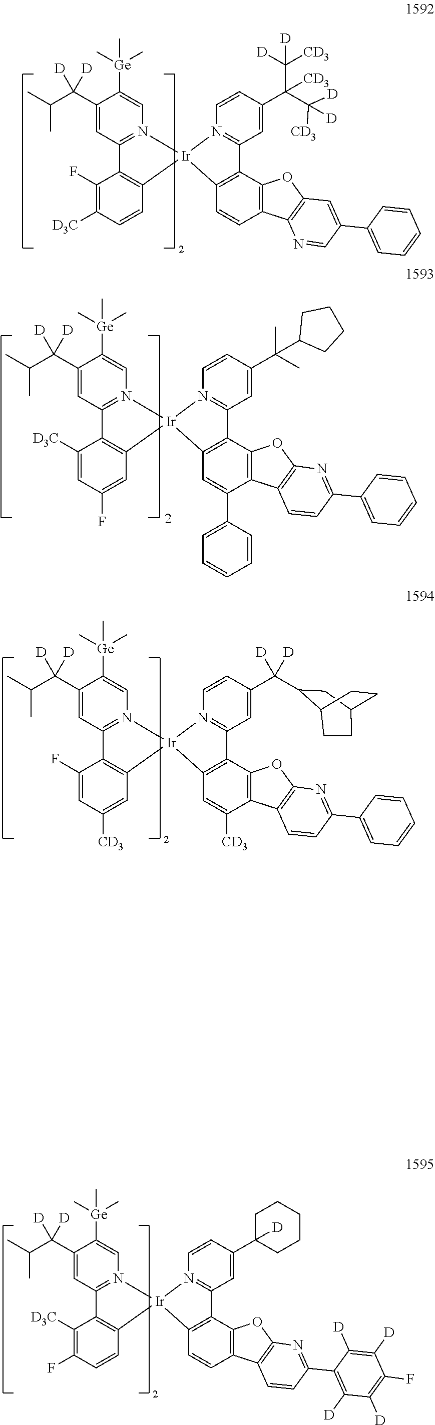

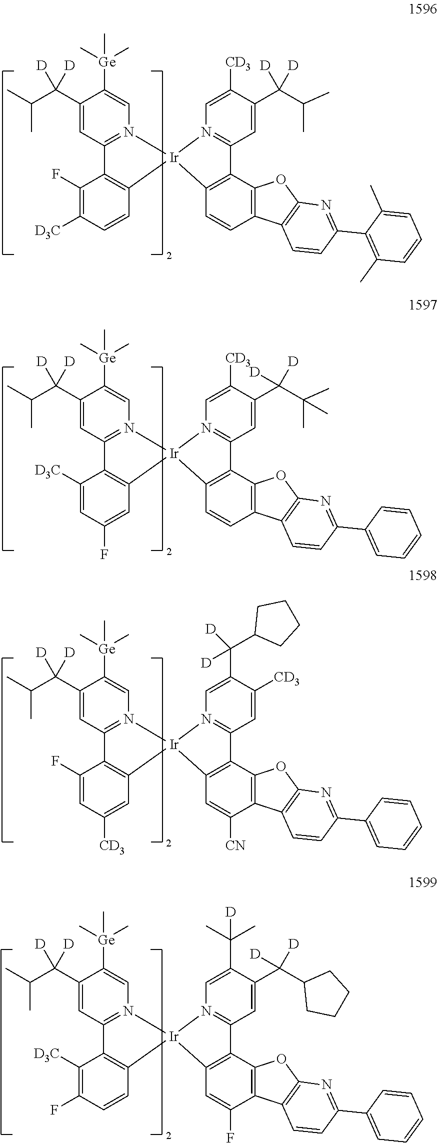

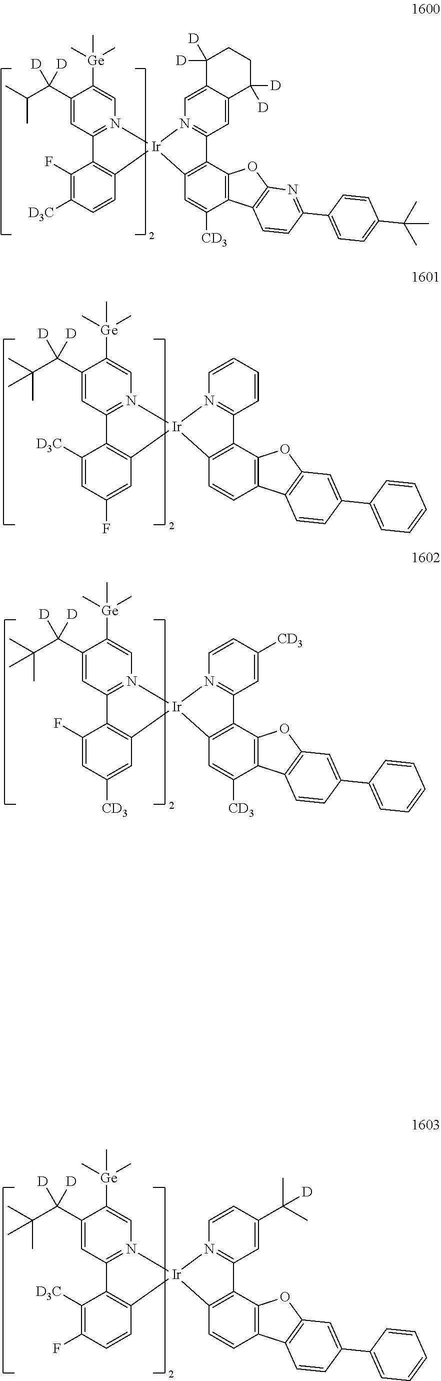

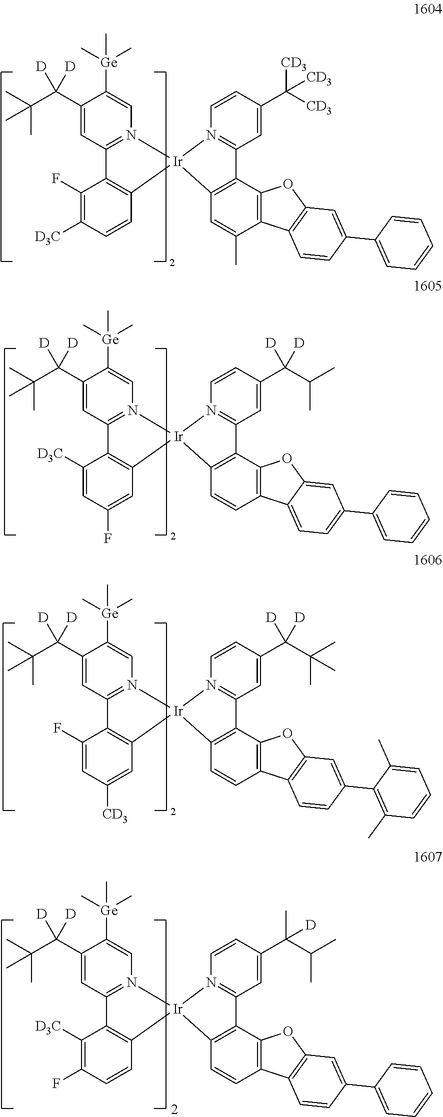

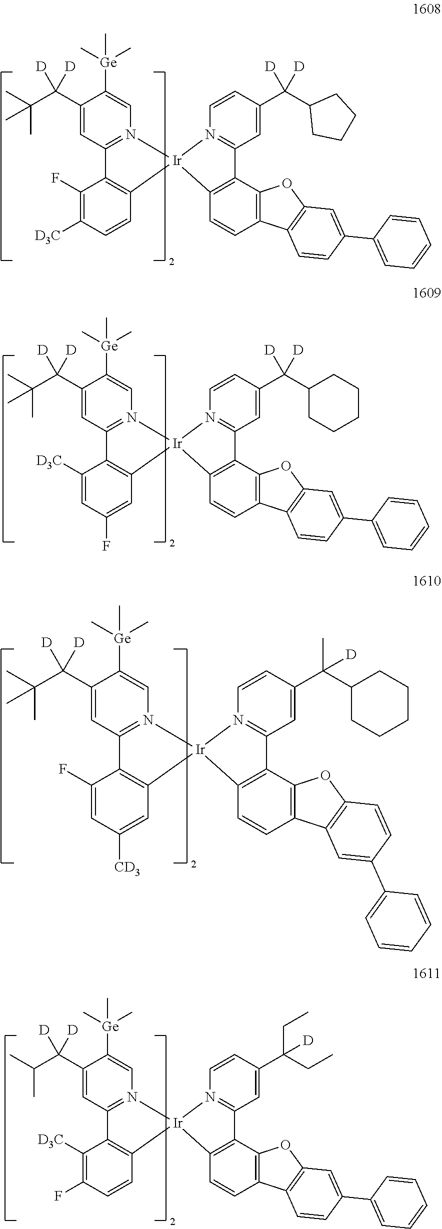

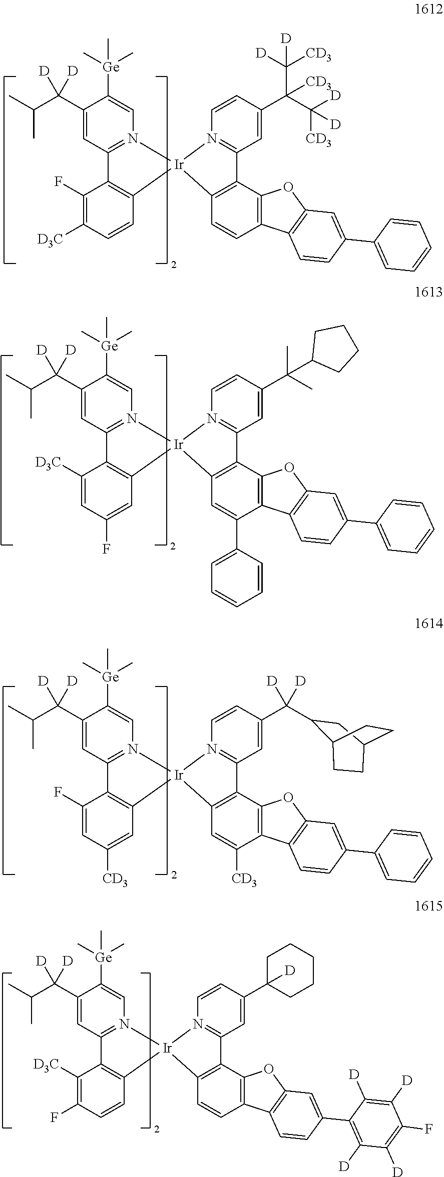

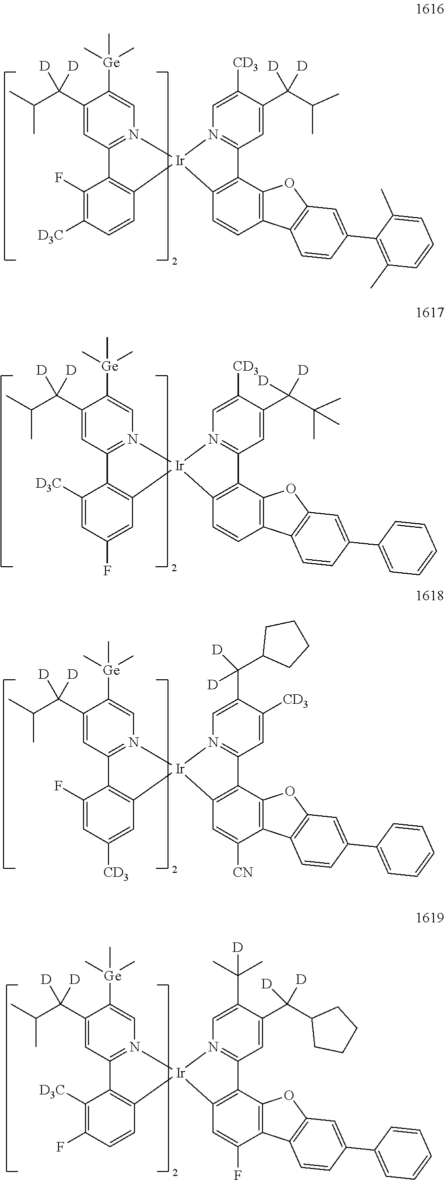

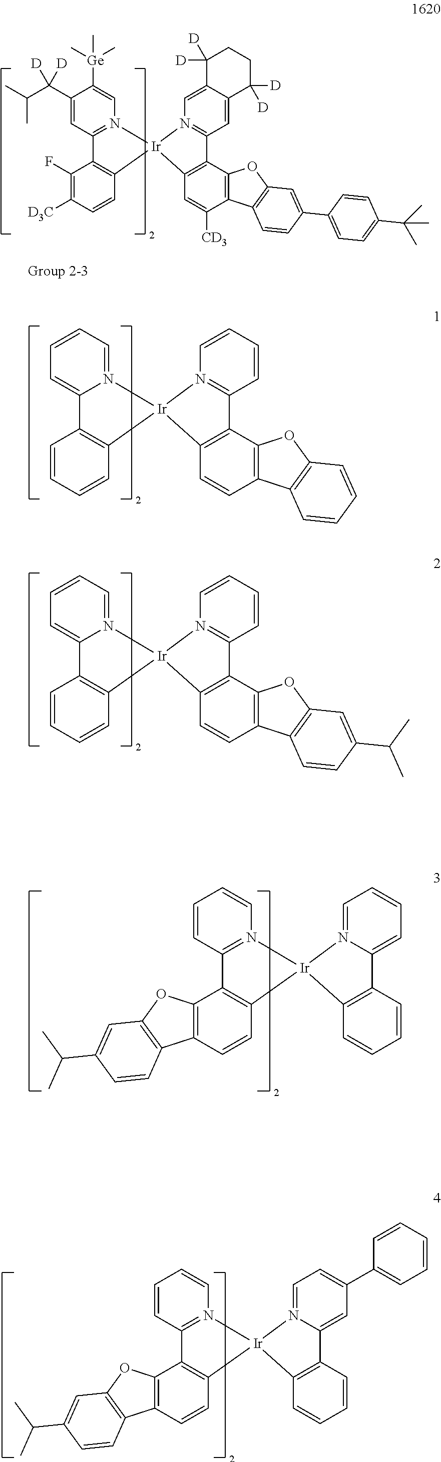

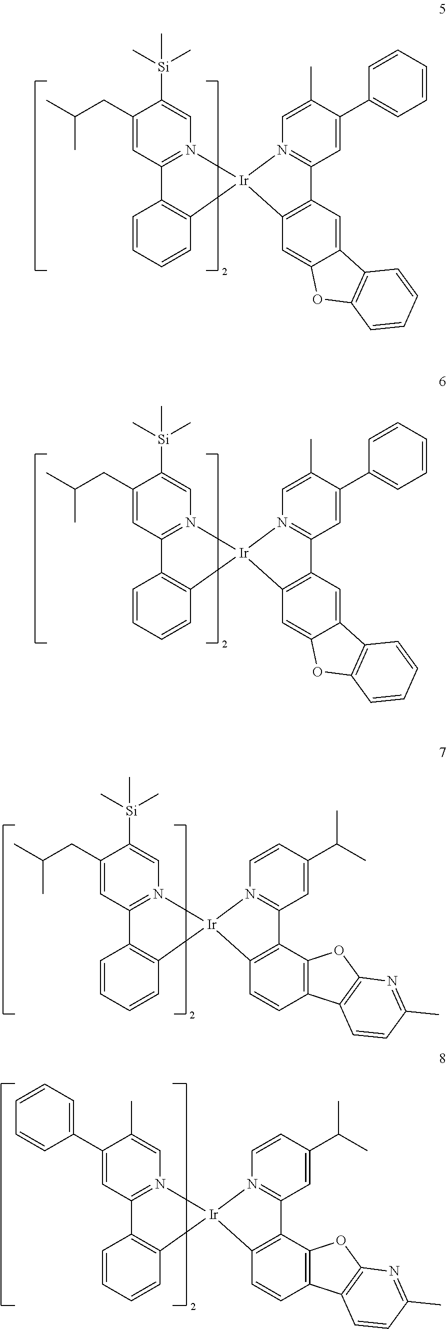

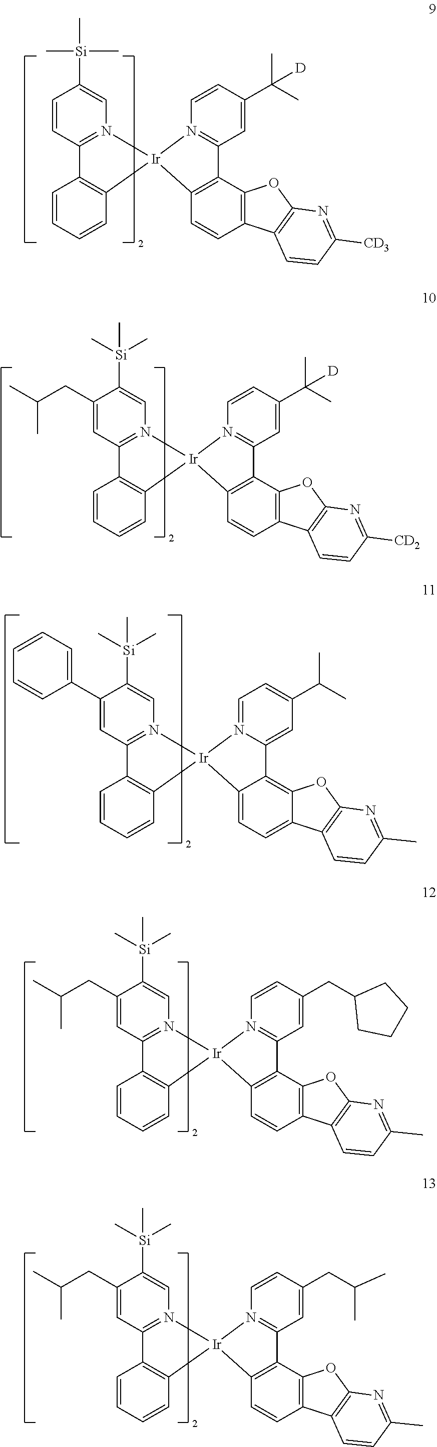

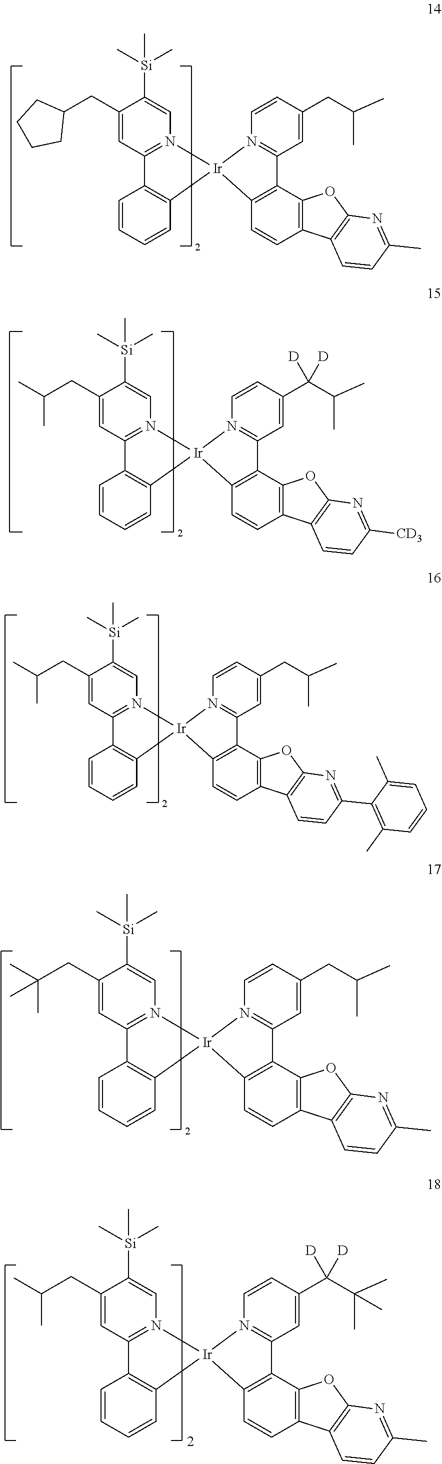

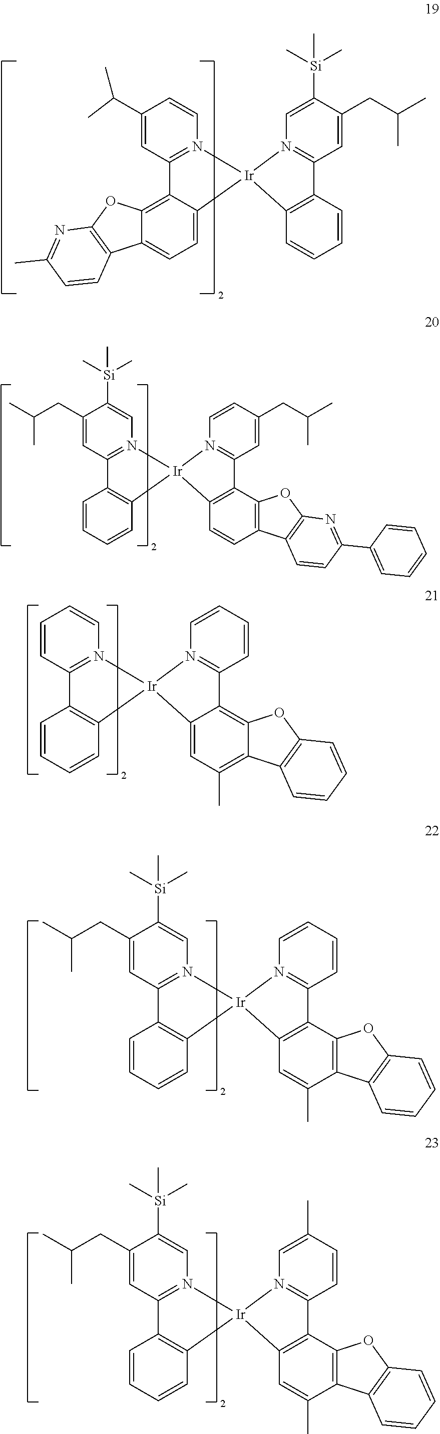

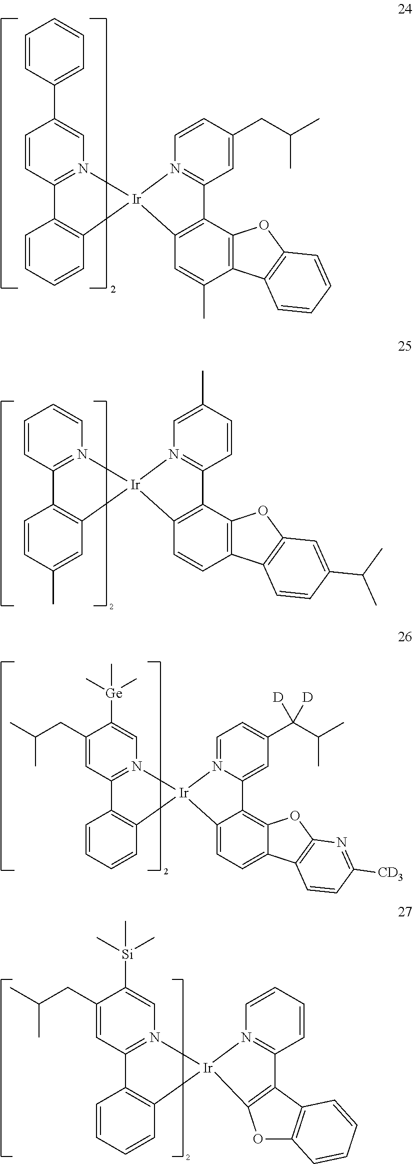

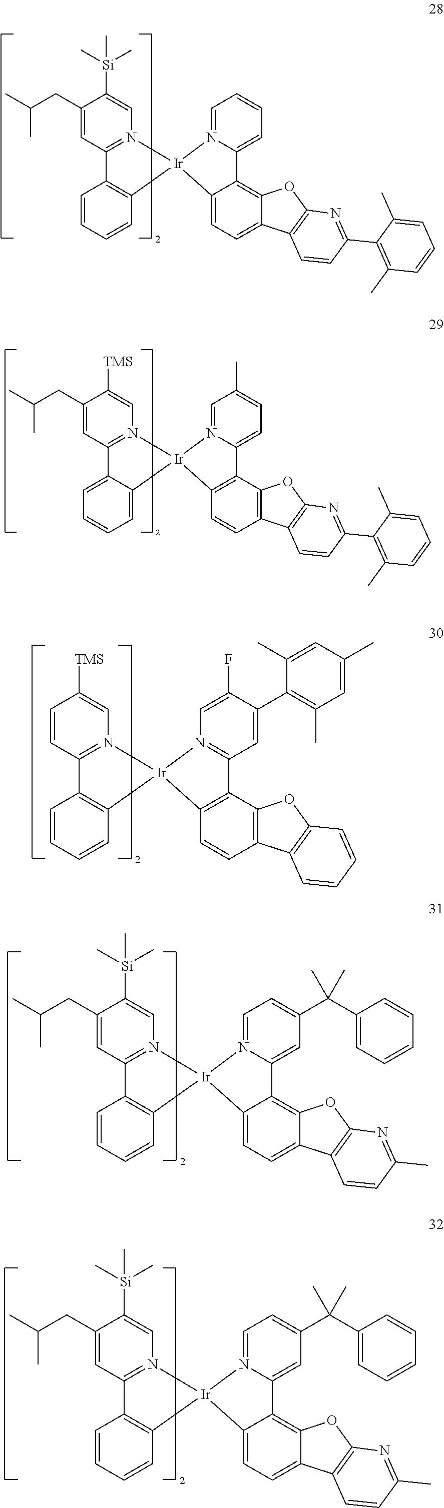

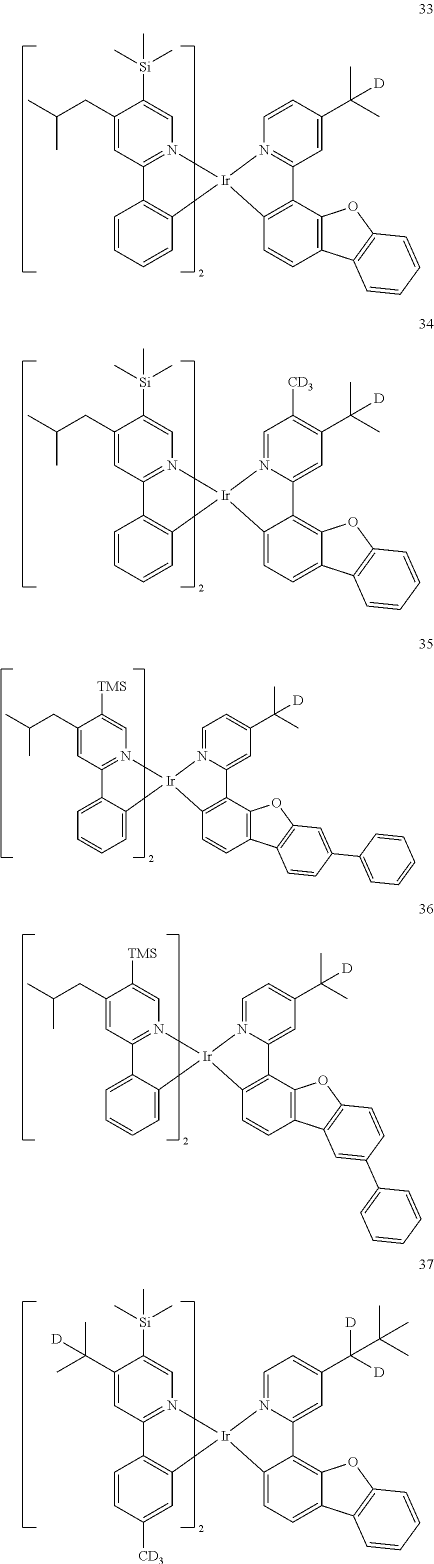

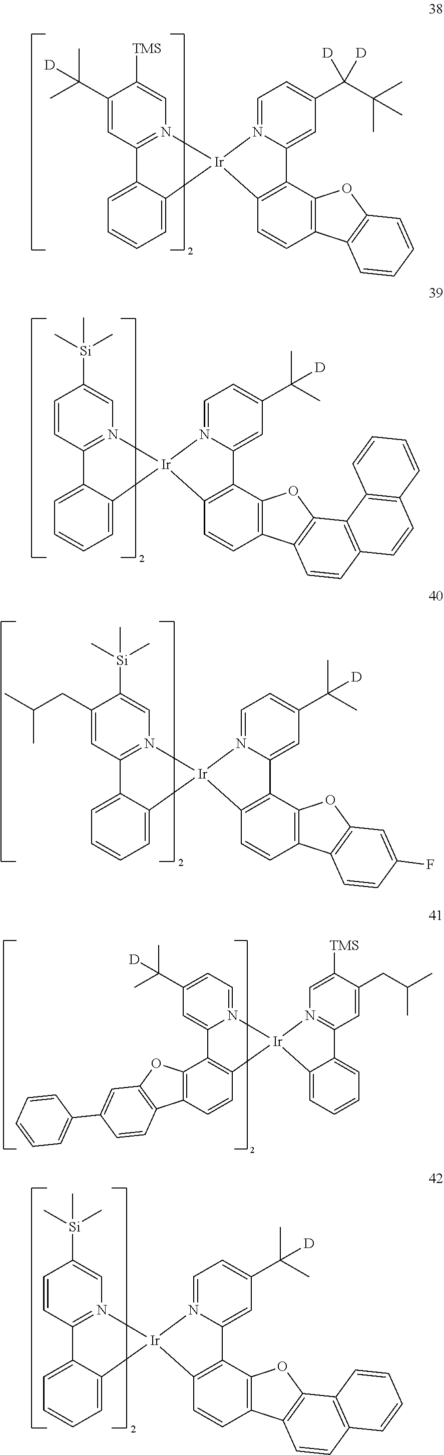

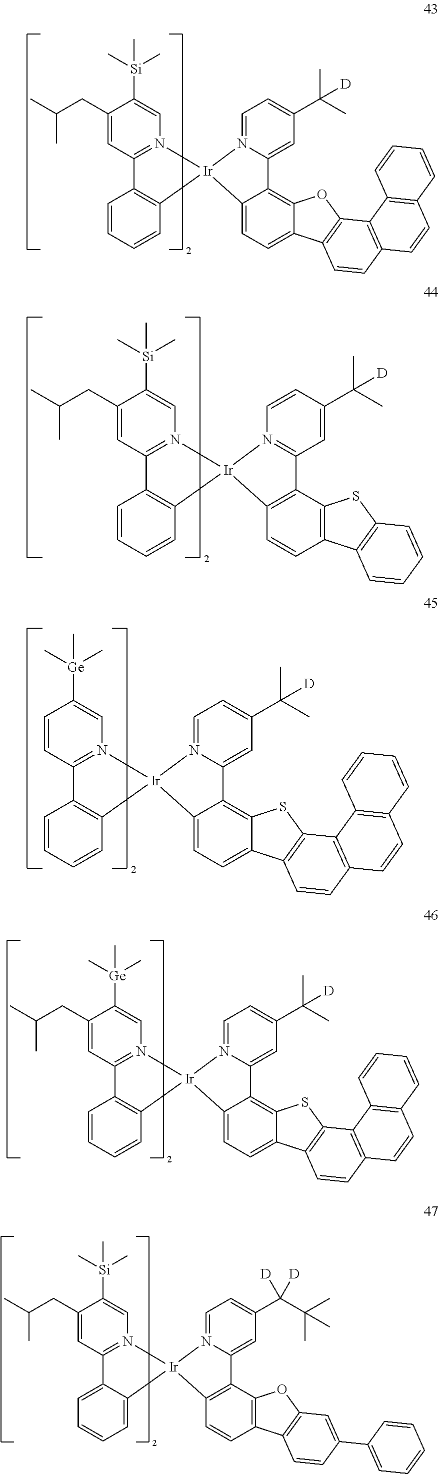

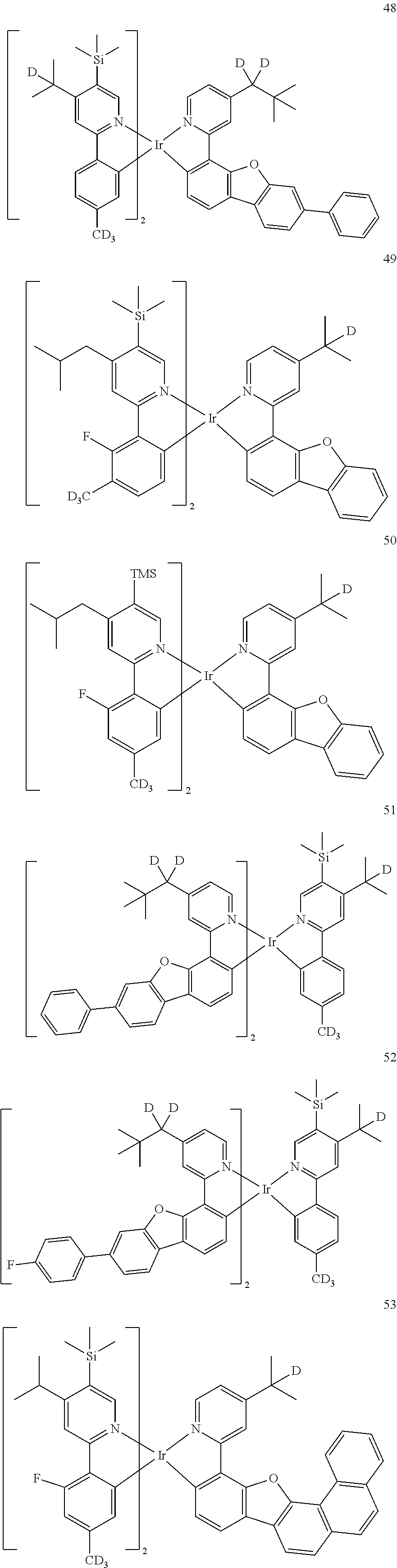

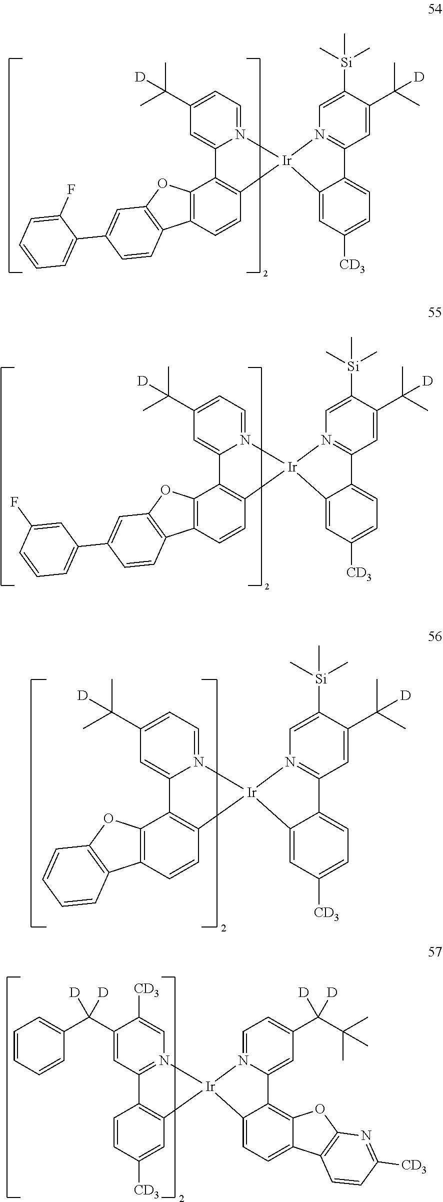

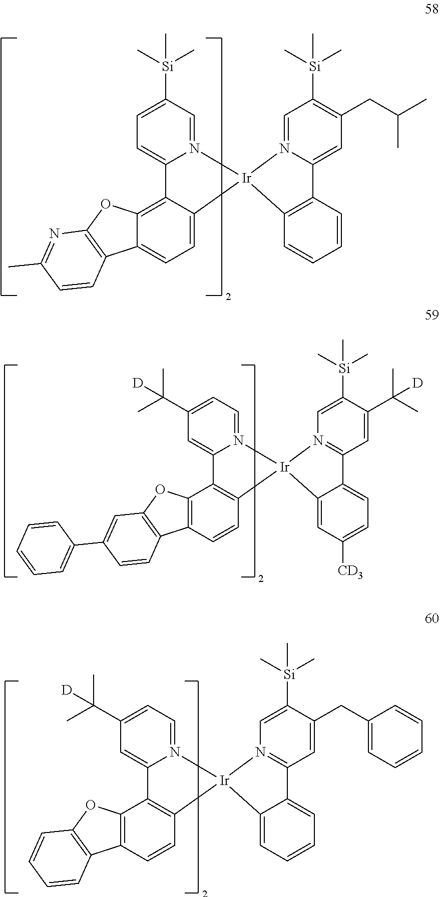

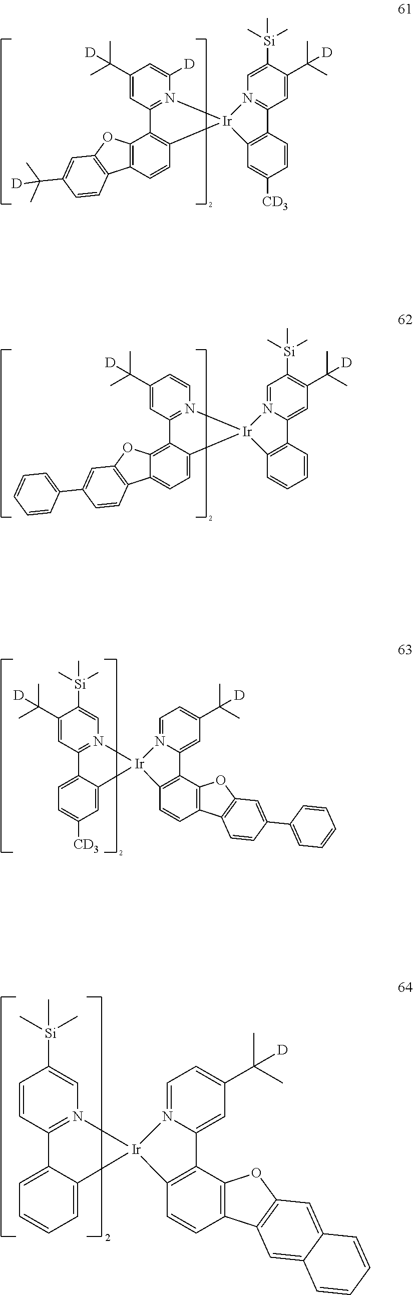

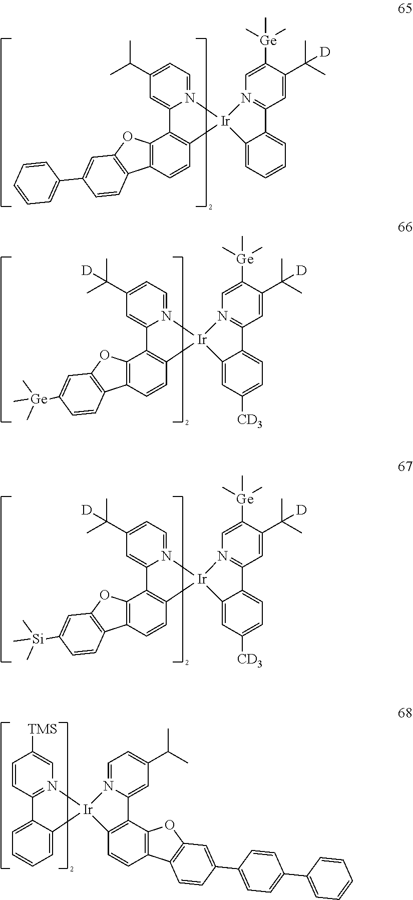

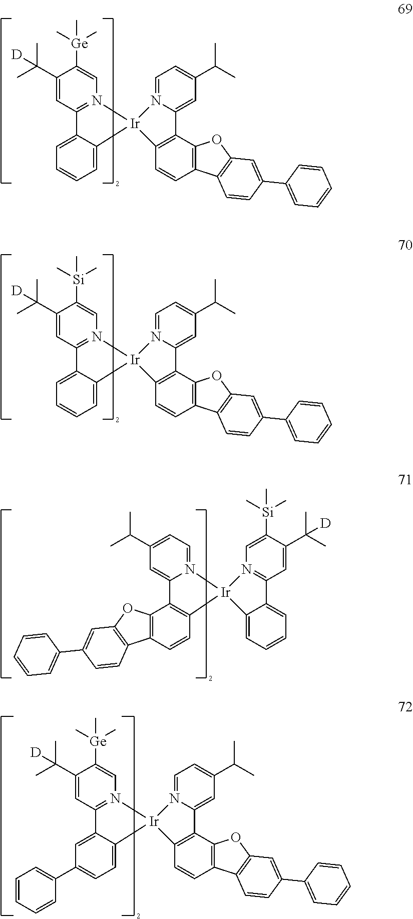

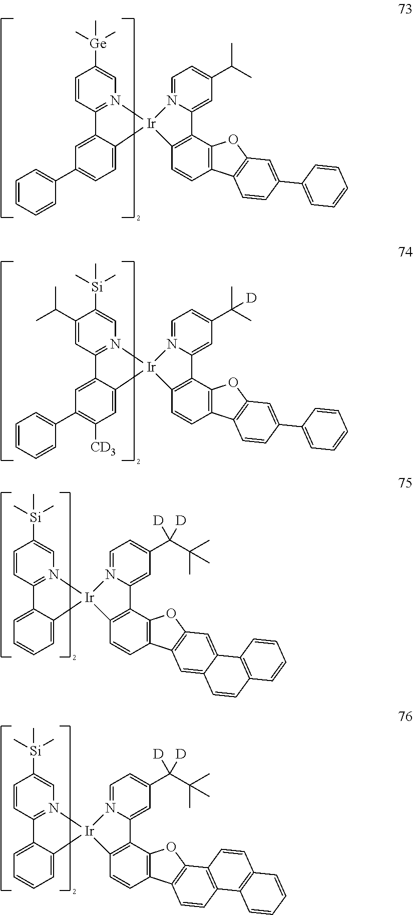

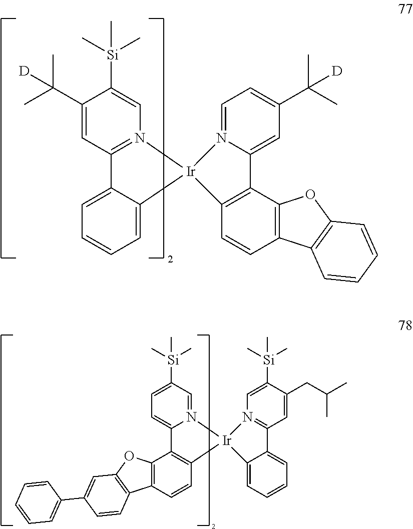

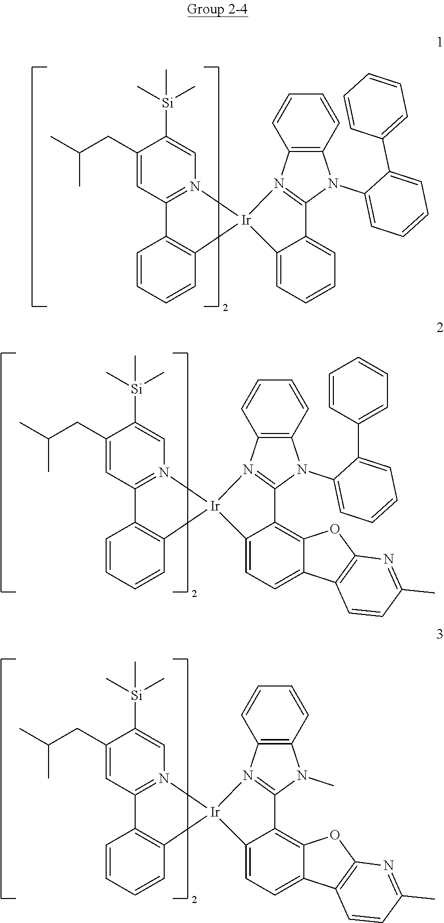

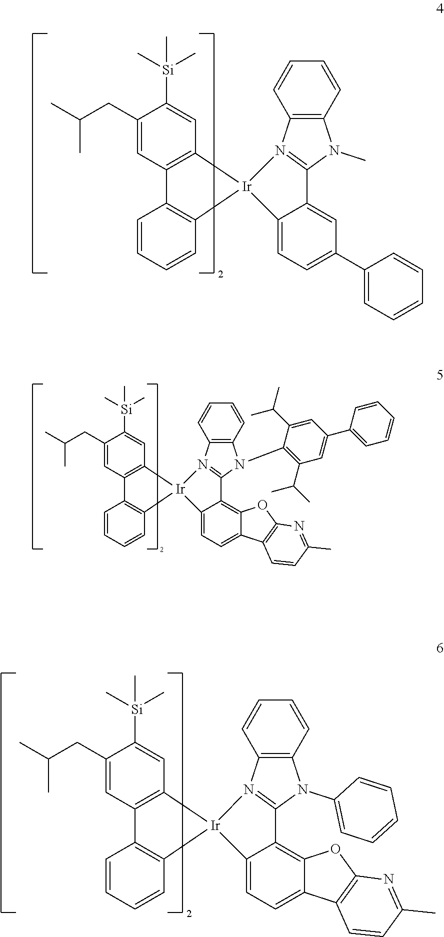

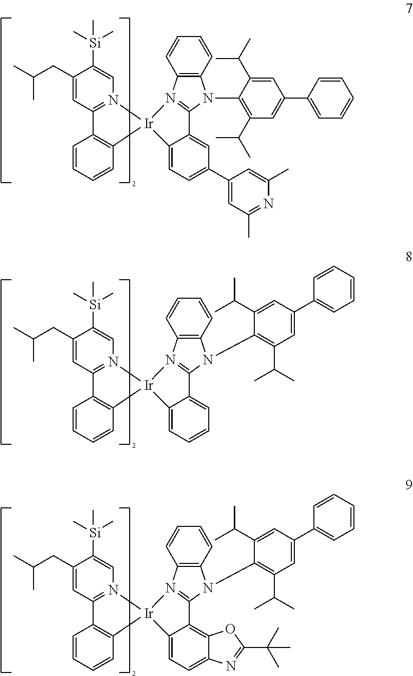

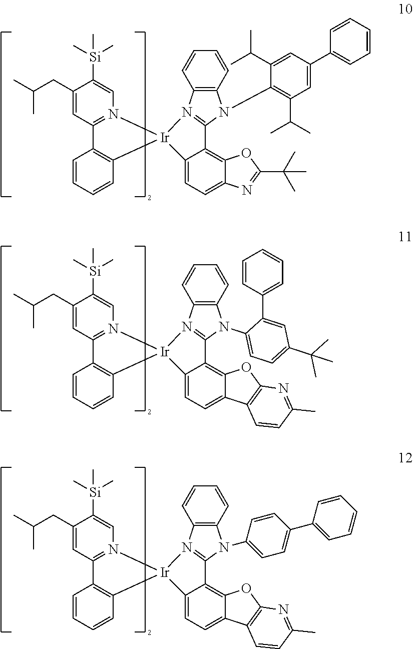

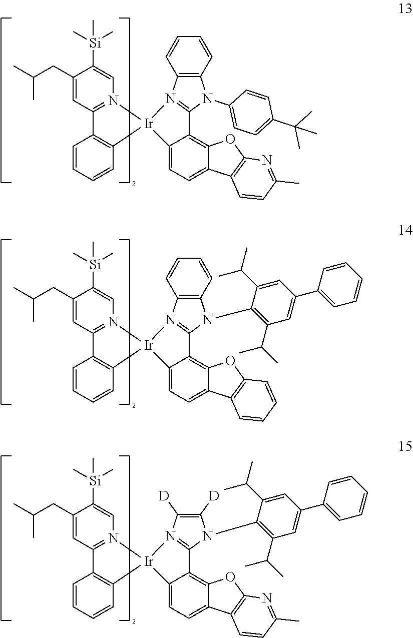

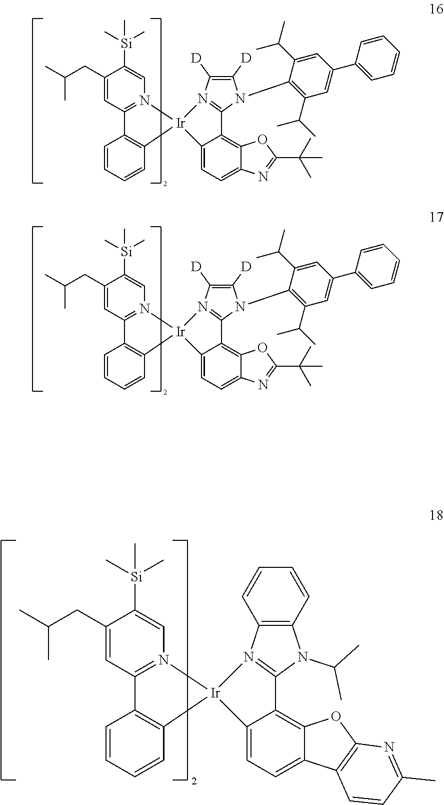

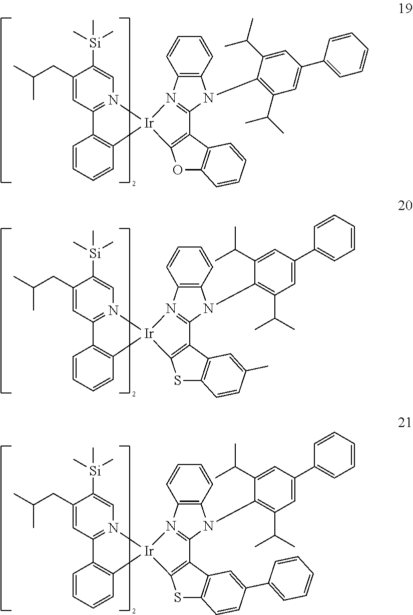

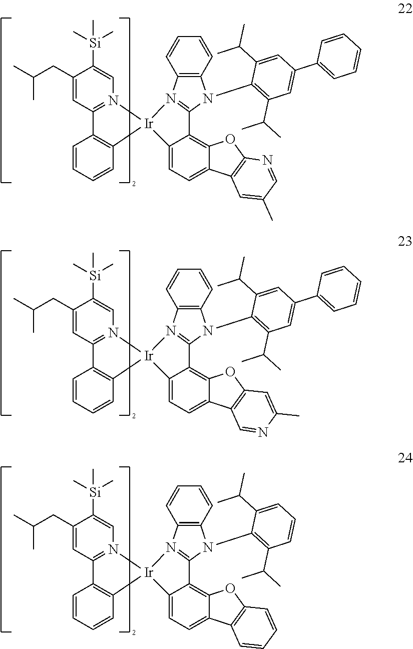

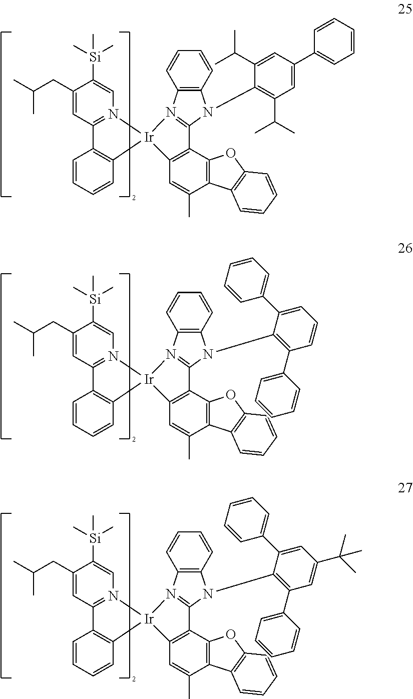

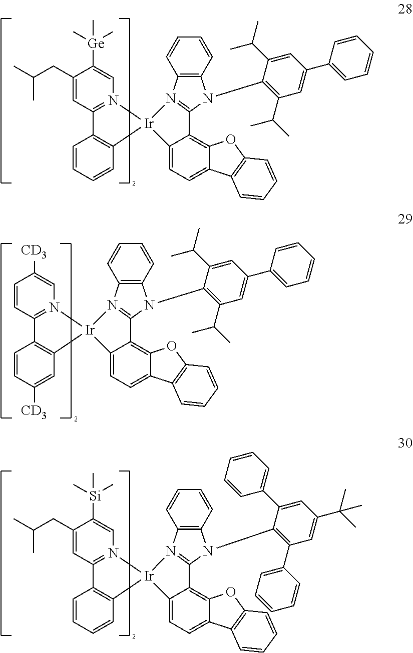

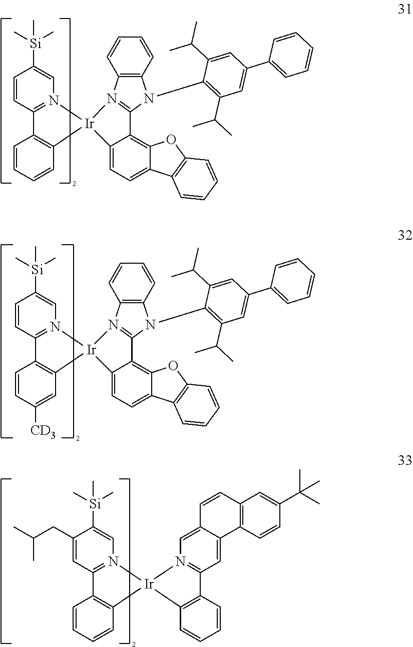

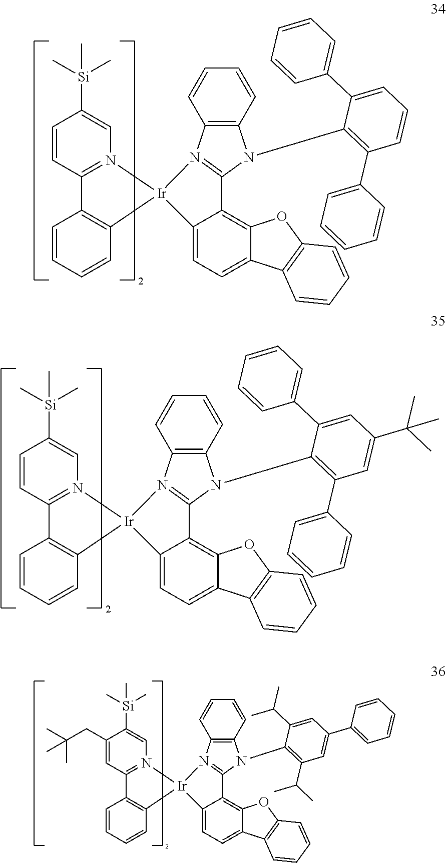

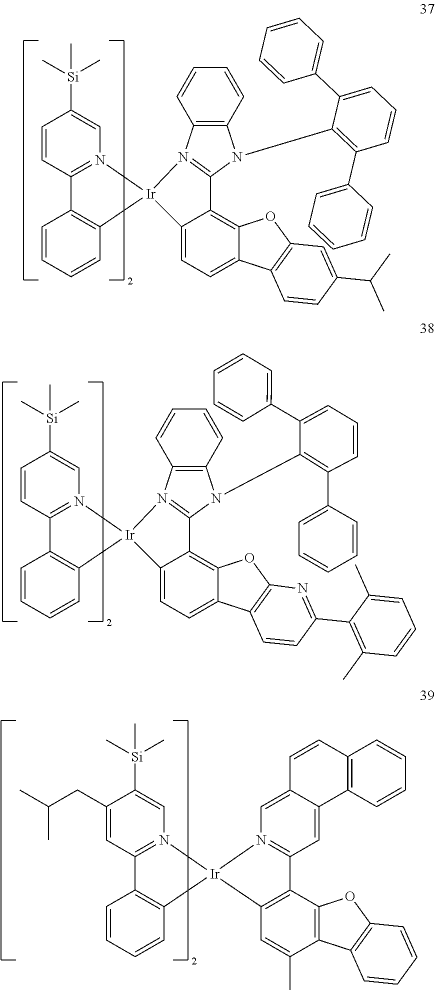

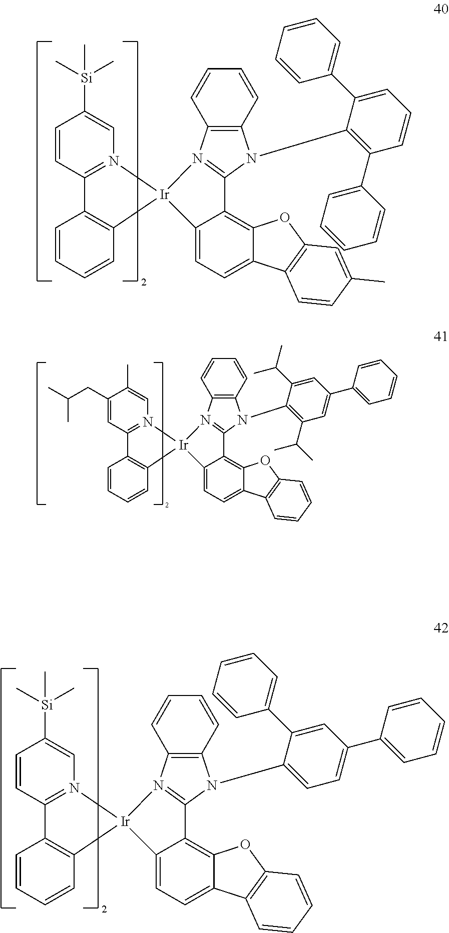

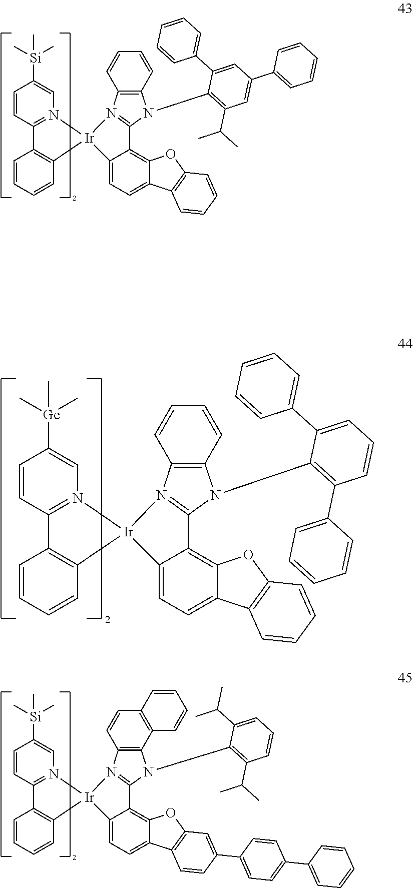

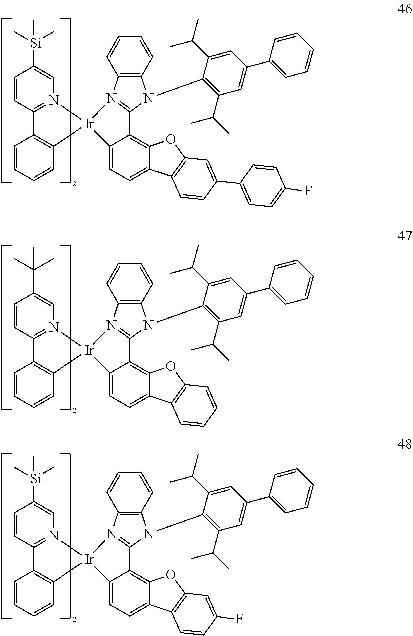

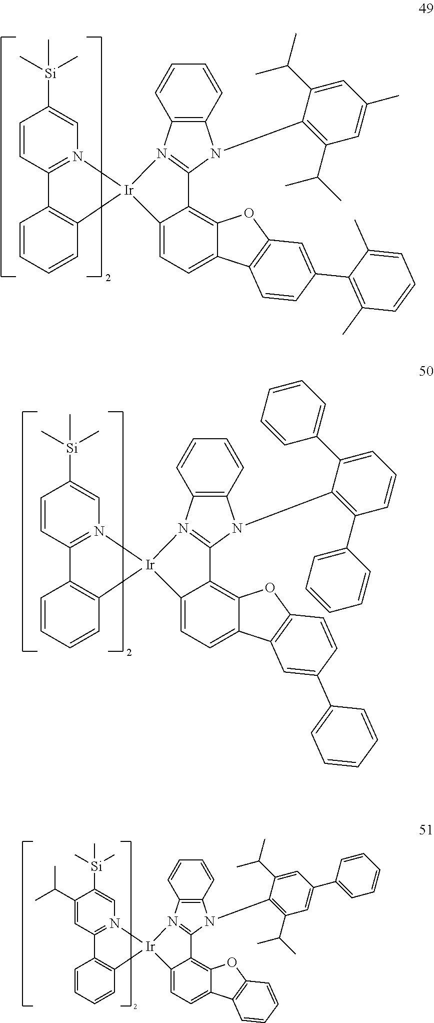

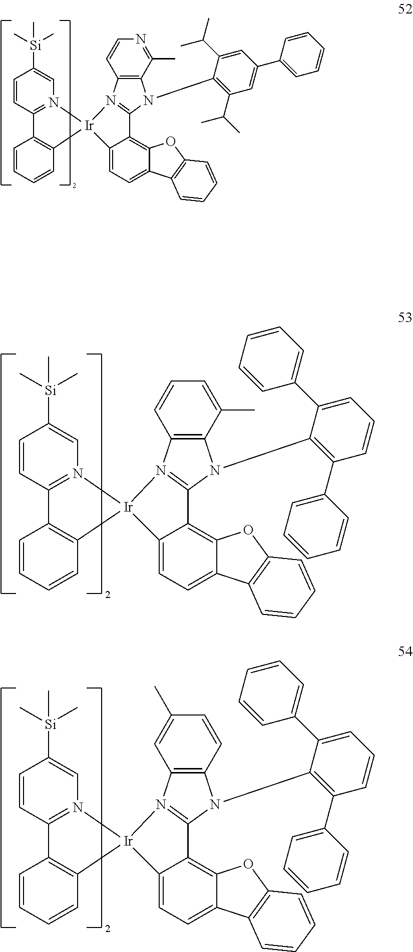

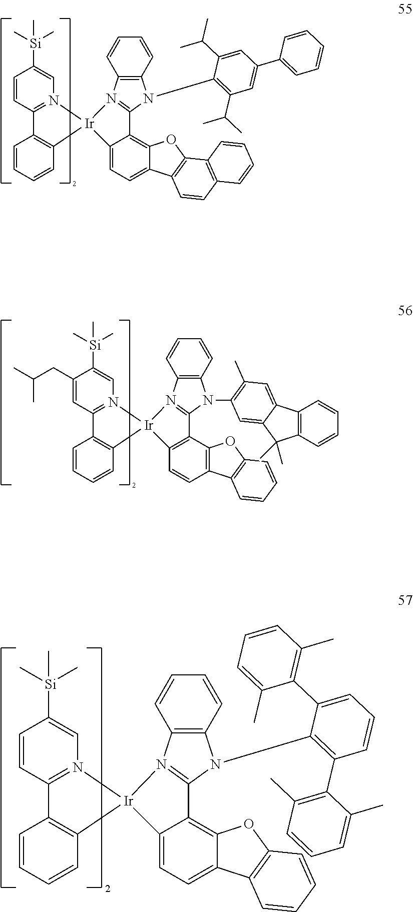

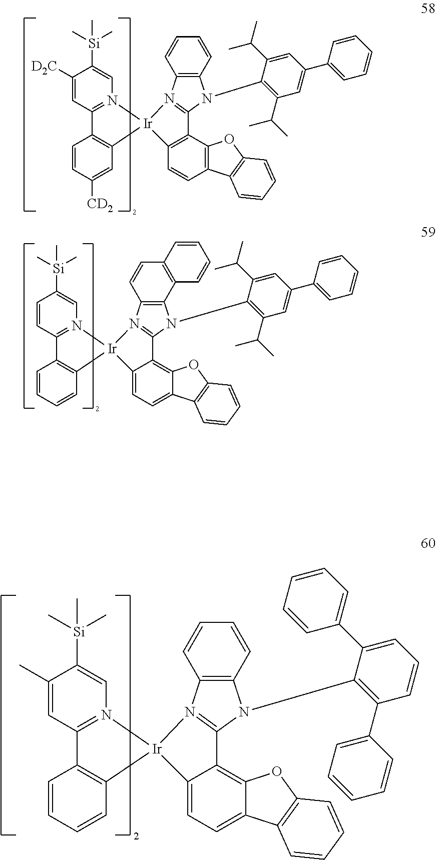

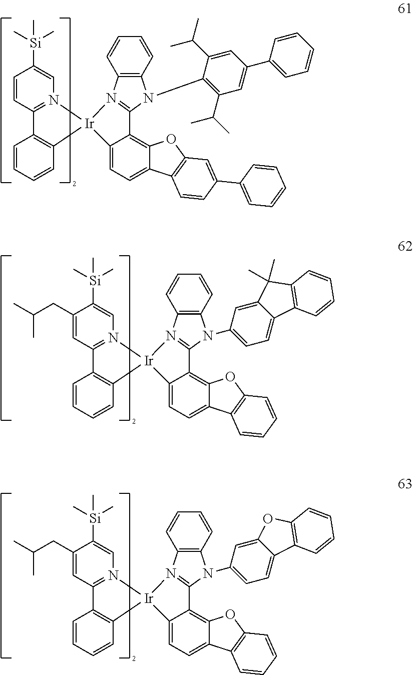

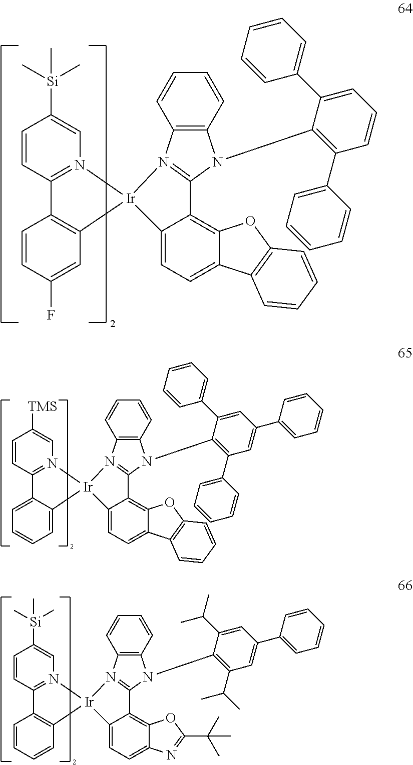

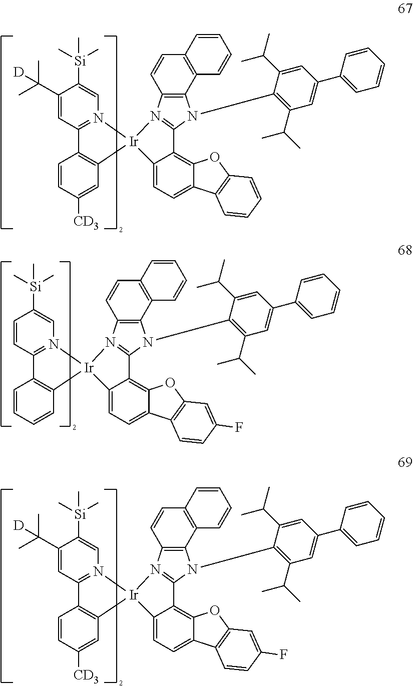

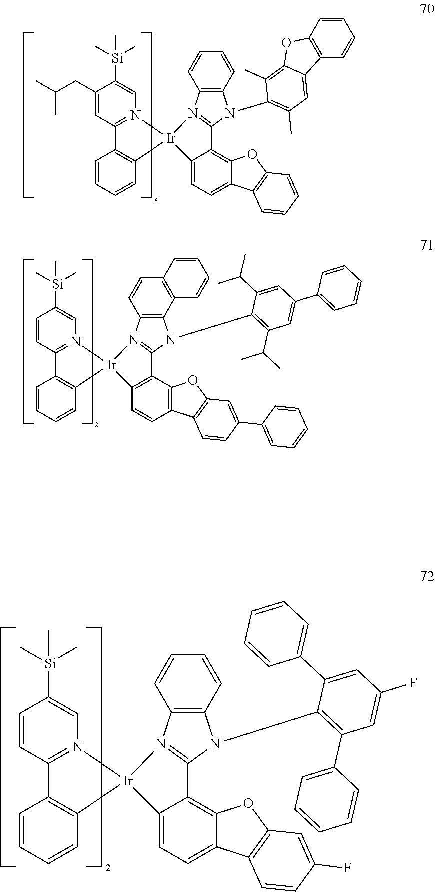

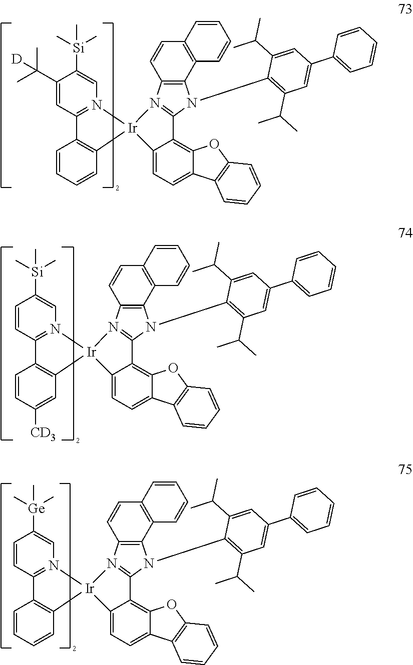

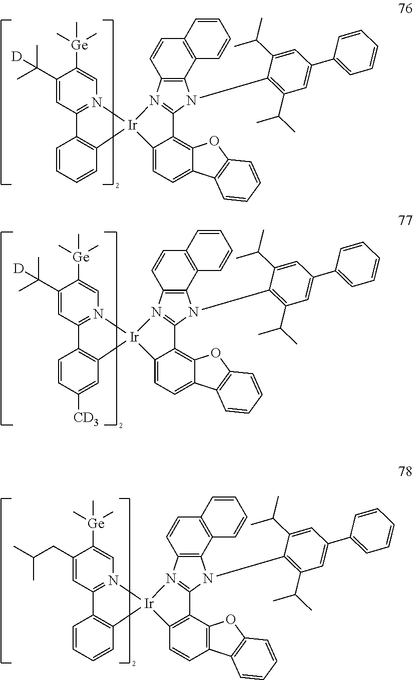

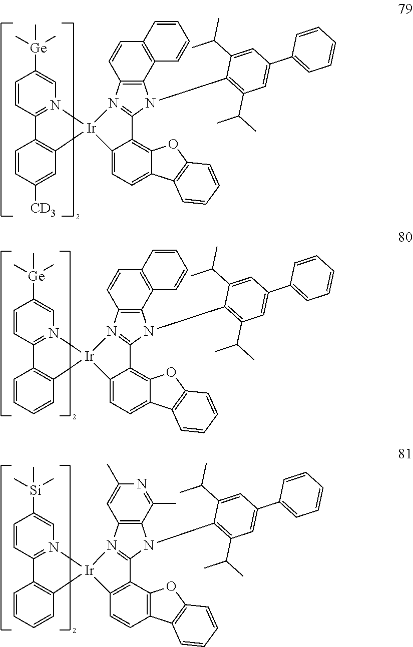

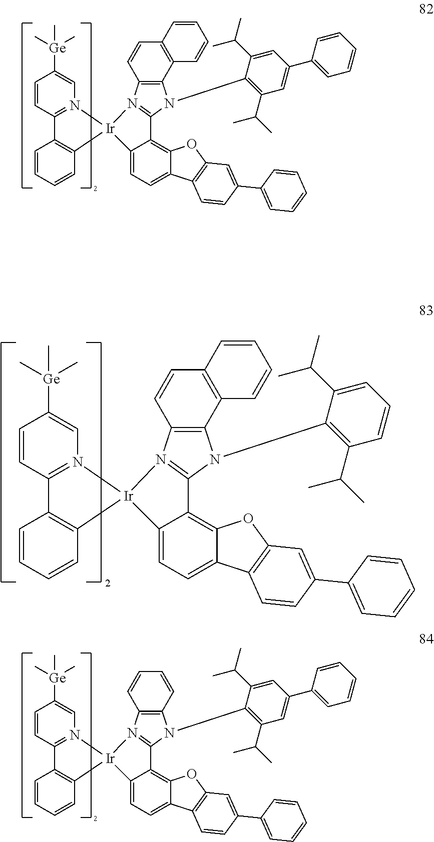

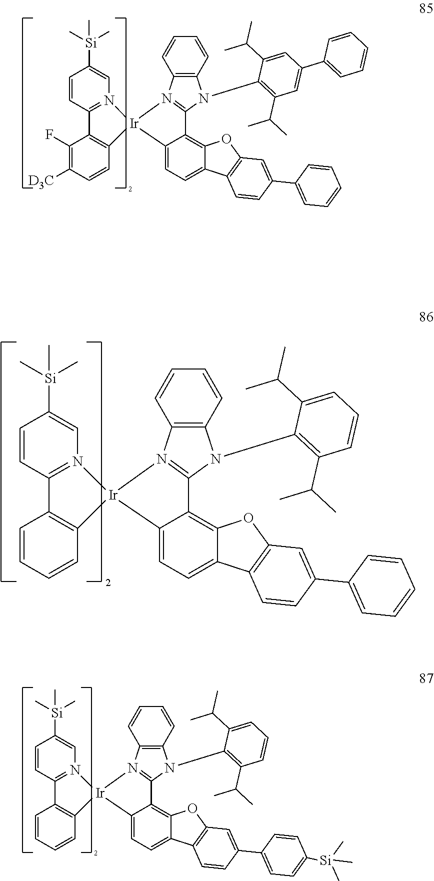

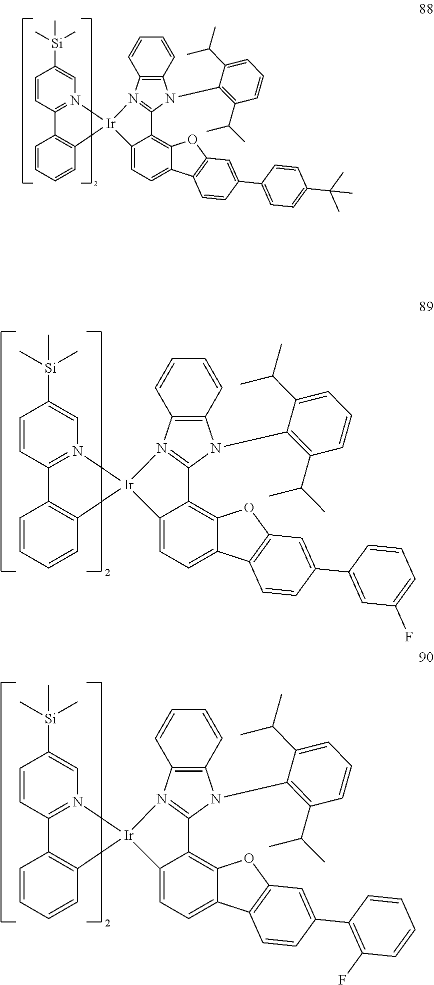

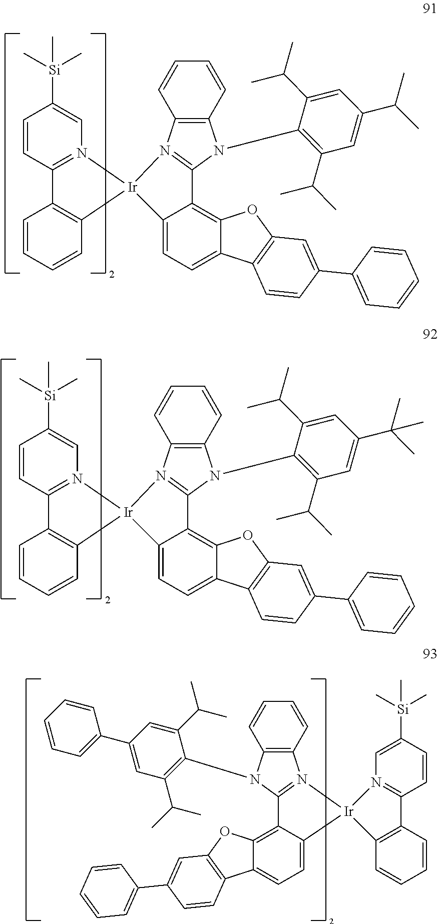

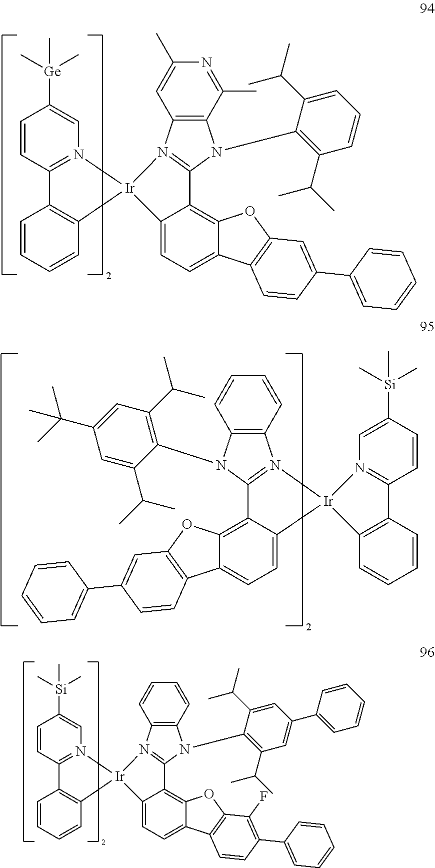

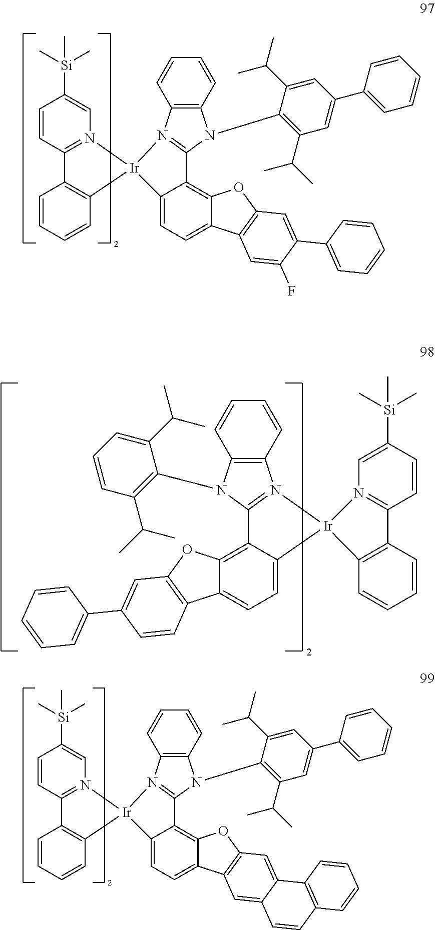

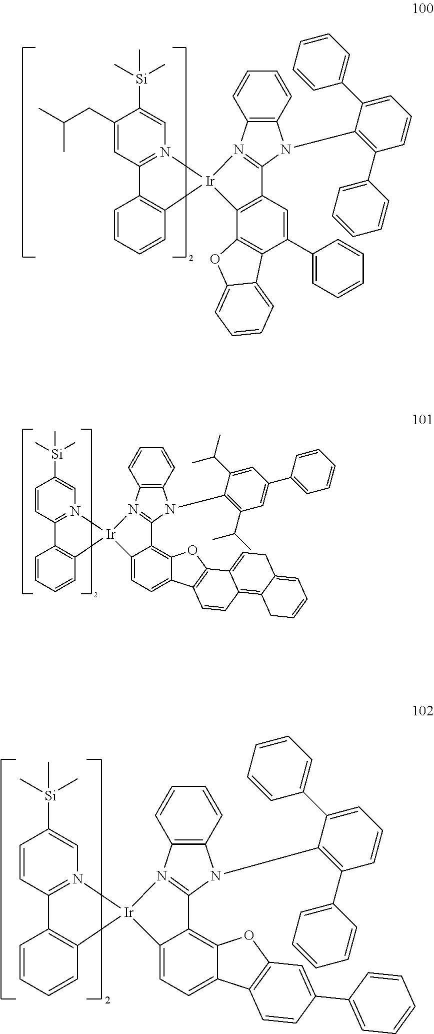

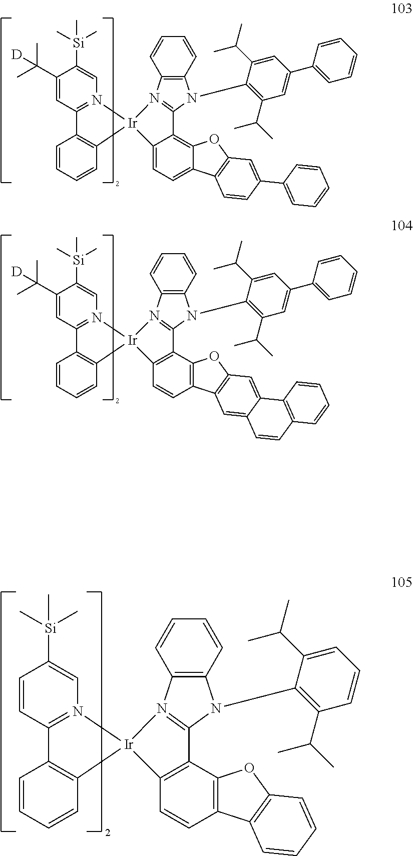

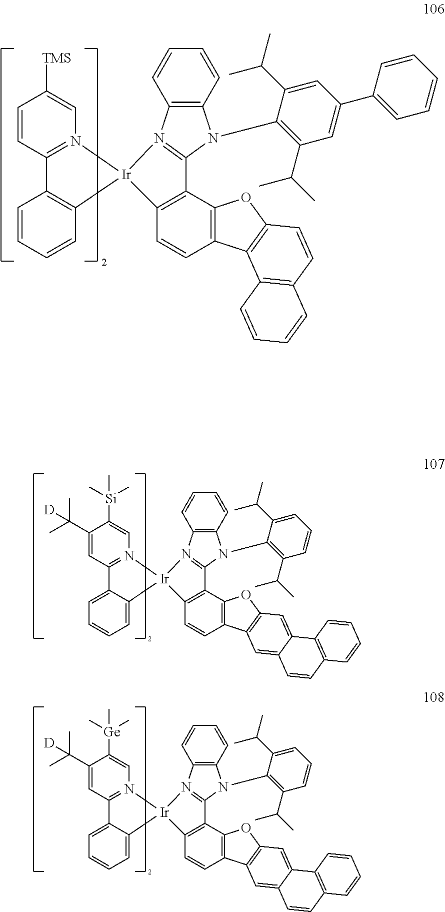

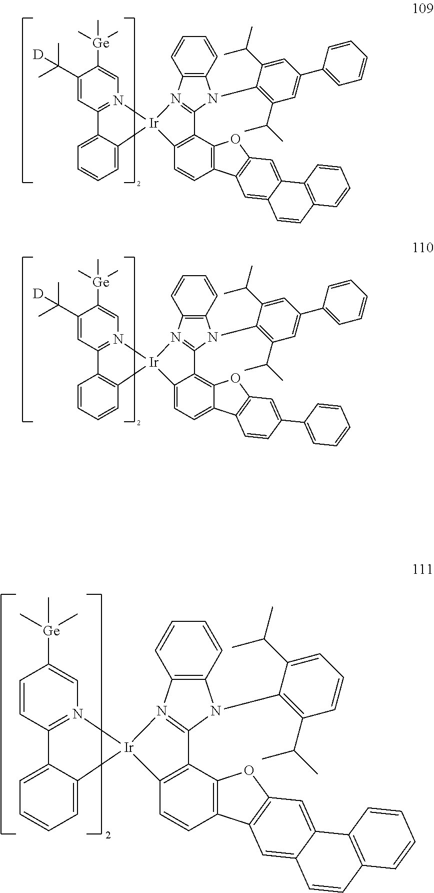

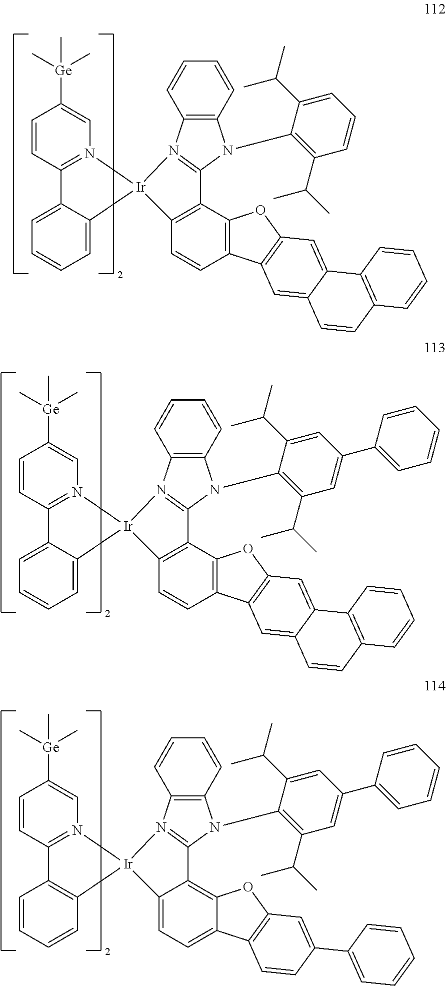

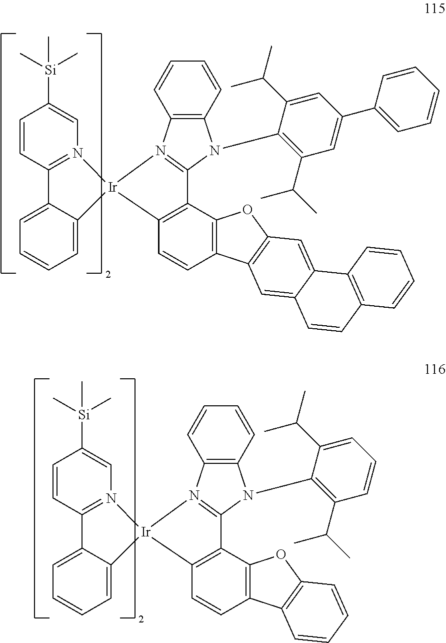

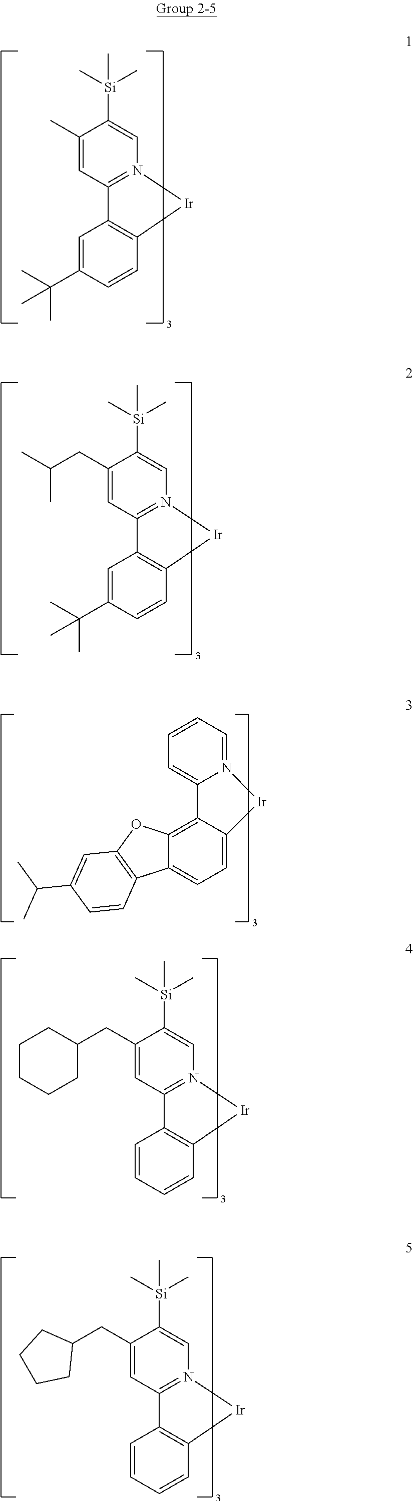

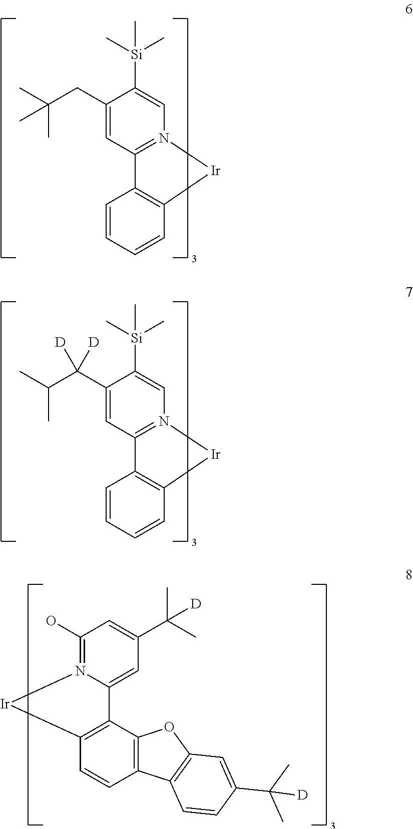

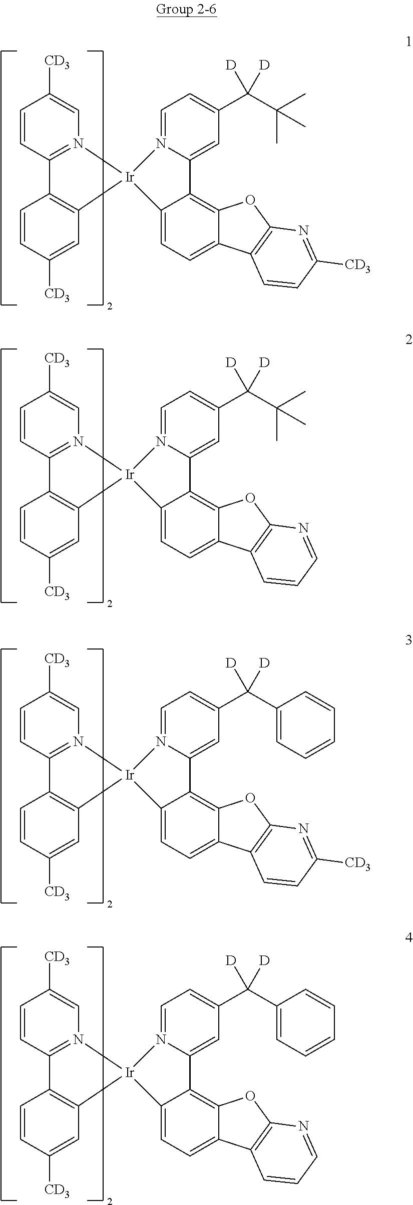

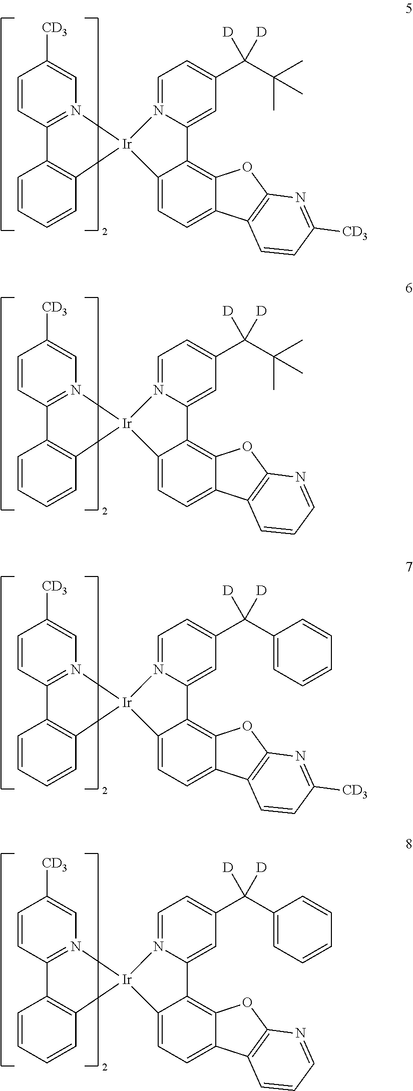

In the present specification, “Ome” is a methoxy group, “TMS” is a trimethylsilyl group, and “TMG” is a trimethylgermyl group.

In one or more embodiments, the iridium-containing organometallic compound may not be a compound of Group B:

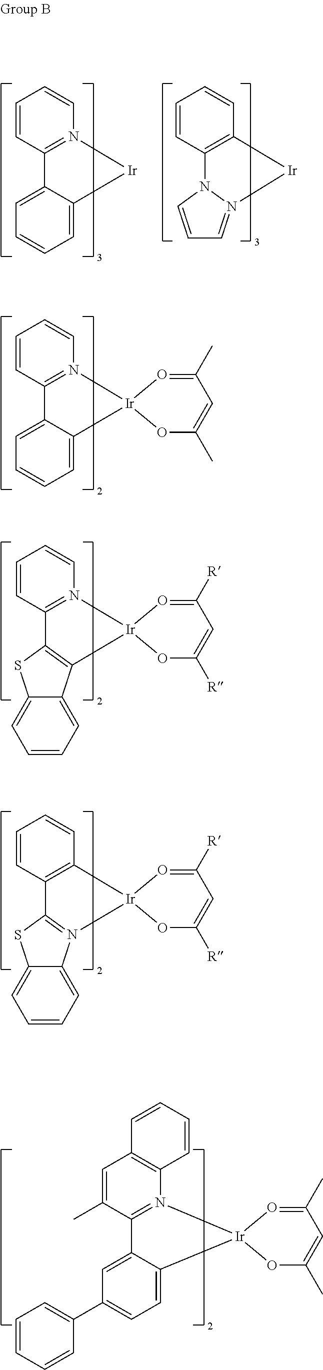

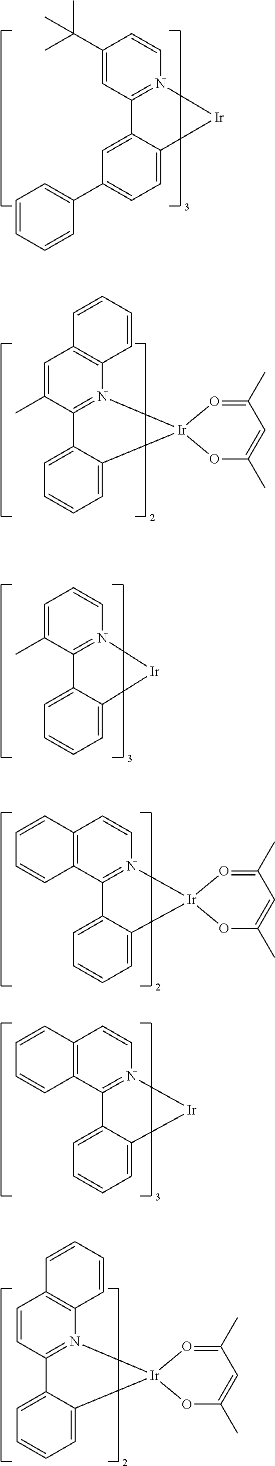

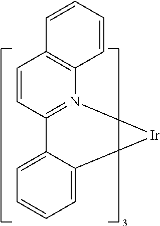

R′ and R″ of Group B may each be an alkyl group.

The fluorescent compound

a) may not include a transition metal, and

b) may include i) B(boron), and ii) O, S, N, or a combination thereof.

In one or more embodiments, the fluorescent compound may include at least one 6-membered ring containing at least one nitrogen atom and at least one boron atom.

In one or more embodiments, the fluorescent compound may be a compound represented by Formula 3 or a compound represented by Formula 4:

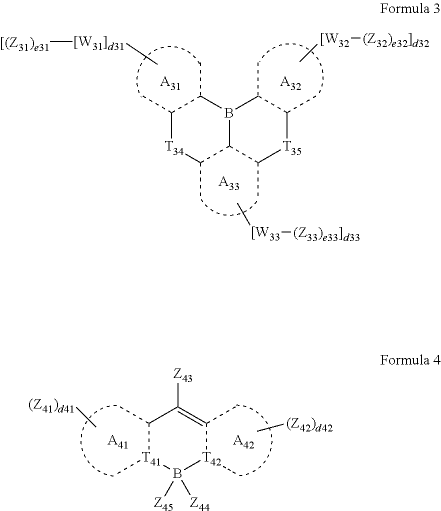

wherein, in Formulae 3 and 4,

ring A₃₁ to ring A₃₃, ring A₄₁, and ring A₄₂ may each independently be a C₅-C₃₀ carbocyclic group or a C₁-C₃₀ heterocyclic group,

T₃₄ may be O, S, or N—[W₃₄—(Z₃₄)ₑ₃₄],

T₃₅ may be O, S, or N—[W₃₅—(Z₃₅)ₑ₃₅],

T₄₁ and T₄₂ may each independently be N or C,

W₃₁ to W₃₃ are each the same as described in connection with W₁ in Formula 2-1,

Z₃₁ to Z₃₅ and Z₄₁ to Z₄₅ are each the same as described in connection with Z₁ in Formula 2-1,

e31 to e35 are each the same as described in connection with e1 in Formula 2-1, and

d31 to d33 and d41 to d42 are each the same as described in connection with d1 in Formula 2-1.

For example, ring A₃₁ to ring A₃₃, ring A₄₁ and ring A₄₂ are each the same as described in connection with ring A₁ in Formula 2-1.

In one or more embodiments, in relation to Formula 3, ring A₃₁ and A₃₂ may each be a benzene group, and ring A₃₃ may be a benzene group, a quinoline group, or an isoquinoline group.

In one or more embodiments, T₃₄ in Formula 3 may be N—[W₃₄—(Z₃₄)ₑ₃₄].

In one or more embodiments, T₃₄ in Formula 3 may be N—[W₃₄—(Z₃₄)ₑ₃₄], and Z₃₄ and ring A₃₁ and/or Z₃₄ and Z₃₁ may be bonded to each other via a single bond, or a linking group including O, S, N, B, C, or a combination thereof.

In one or more embodiments, T₃₅ in Formula 3 may be N—[W₃₅—(Z₃₅)ₑ₃₅].

In one or more embodiments, T₃₅ in Formula 3 may be N—[W₃₅—(Z₃₅)ₑ₃₅], and Z₃₅ and ring A₃₂ and/or Z₃₅ and Z₃₂ may be bonded to each other via a single bond or a linking group including O, S, N, B, C, or a combination thereof.

In one or more embodiments, ring A₄₁ and ring A₄₂ in Formula 4 may each be pyrrolyl. For example, T₄₁ and T₄₂ may each be N.

For example, the fluorescent compound may be a compound of Group 3 or Group 4:

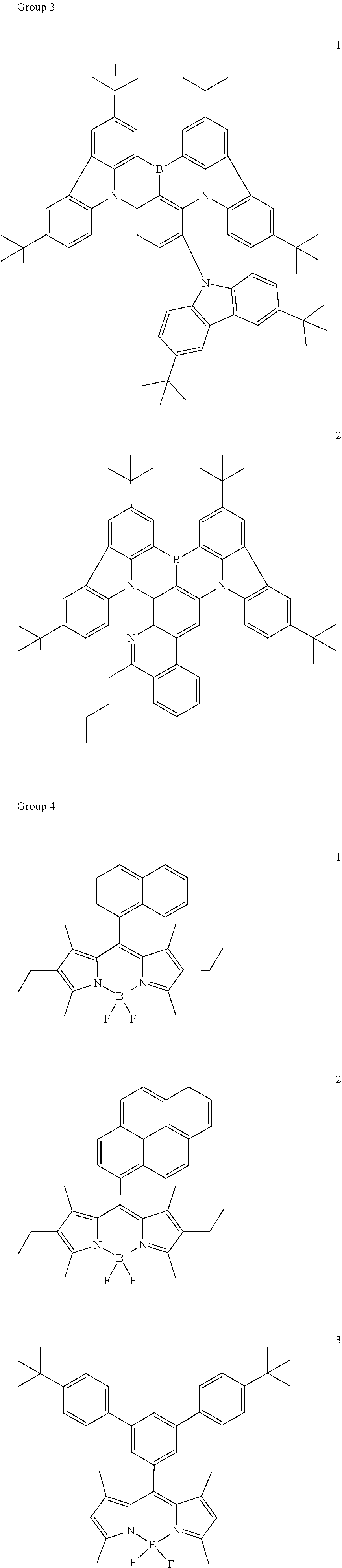

A weight ratio of the first compound to the second compound included in the mixture including the first compound and the second compound may be about 90:10 to about 10:90, about 80:20 to about 20:80, about 70:30 to about 30:70, or about 60:40 to about 40:60.

### Descriptions of FIGS. 2 to 31

FIGS. 2 to 31 each show a cross-sectional view of an OLED substrate according to one or more embodiments.

The OLED substrate of FIG. 2 has a tandem structure in which a first electrode 10, a blue first emission unit 31B, a green second emission unit 32G, and a second electrode 50 are vertically stacked in sequence. That is, the OLED substrate of FIG. 2 includes one blue emission unit 31B and one green emission unit 32G.

A color control unit 2 may be located above the second electrode 50. That is, the green second emission unit 32G of FIG. 2 may be located closer to the color control unit 2 than the blue first emission unit 31B.

The first electrode 10 may be anode, which is a hole injection electrode, and the second electrode 50 may be a cathode, which is an electron injection electrode. Alternatively, the first electrode 10 may be a cathode, which is an electron injection electrode, and the second electrode 50 may be an anode, which is a hole injection electrode.

A thin-film transistor (TFT) array substrate including a plurality of TFT (not shown) may be provided under the first electrode 10, and an OLED substrate 1 may be provided on the TFT array substrate.

The first electrode 10 may be formed by, for example, applying a material for forming the first electrode 10 onto the substrate by using a deposition or sputtering method. The first electrode 10 may be an anode. The material for forming the first electrode 10 may include materials with a high work function to facilitate hole injection. The first electrode 10 may be a reflective electrode, a semi-transmissive electrode, or a transmissive electrode. The material for forming the first electrode 10 may be indium tin oxide (ITO), indium zinc oxide (IZO), tin oxide (SnO₂), or zinc oxide (ZnO). In one or more embodiments, the material for forming the first electrode 10 may be metal, such as magnesium (Mg), aluminum (Al), silver (Ag), aluminum-lithium (Al—Li), calcium (Ca), magnesium-indium (Mg—In), or magnesium-silver (Mg—Ag).

The first electrode 10 may have a single-layered structure or a multi-layered structure including a plurality of layers. For example, the first electrode 10 may have a three-layered structure of ITO/Ag/ITO.

The first electrode 10 may be a patterned element corresponding to each subpixel area and electrically connected to each TFT element of the TFT array substrate (not shown).

The blue first emission unit 31B may include a blue luminescent compound (i.e., a blue light-emitting compound).

The blue luminescent compound may include a blue phosphorescent compound, and a blue fluorescent compound (thermal activated delayed fluorescence (TADF) compound and/or prompt fluorescent compound).

In one or more embodiments, the blue luminescent compound may be an iridium-containing organometallic compound or a platinum-containing organometallic compound. The iridium-containing organometallic compound may include a ligand having a carbene moiety, and the carbon of the carbene moiety of the ligand and the iridium of the iridium-containing organometallic compound may be connected by a chemical bond.

In one or more embodiments, the blue luminescent compound may be a fluorescent compound including at least one boron (B) atom and at least one nitrogen (N) atom. In one or more embodiments, the blue luminescent compound may include a C₆-C₆₀ polycyclic group in which a 6-membered ring containing boron atom and a nitrogen atom as ring-forming atoms and a cyclic group are condensed with each other.

The green second emission unit 32G may include a mixture of the first compound and the second compound as described herein.

The second electrode 50 may be the cathode. A material for forming the second electrode 50 may be metal, an alloy, an electrically conductive compound, or a combination thereof, which have a relatively low work function. For example, lithium (Li), magnesium (Mg), aluminum (Al), silver (Ag), aluminum-lithium (Al—Li), calcium (Ca), magnesium-indium (Mg—In), magnesium-silver (Mg—Ag), or the like may be used as the material for forming the second electrode 50.

The second electrode 50 may be an unpatterned common electrode, or may be patterned with a plurality of electrode elements.

A protective layer (not shown) may additionally be located on the second electrode 50. In one or more embodiments, the protective layer may include a transparent insulating material.

Referring to FIG. 1, the blue light emitted from the blue first emission unit 31B and the green light emitted from the green second emission unit 32G pass through the second electrode 50 and the color of each light is adjusted by the color control unit 2 and then the adjusted each light is emitted toward outside the light-emitting device.

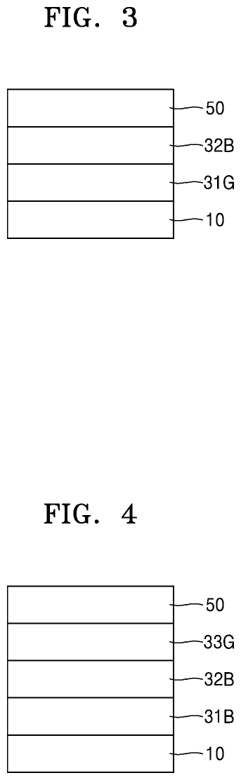

The OLED substrate of FIG. 3 has a tandem structure in which the first electrode 10, a green first emission unit 31G, a blue second emission unit 32B, and the second electrode 50 are vertically stacked in this order.

The OLED substrate may include two blue emission units and one green emission unit, as illustrated in FIGS. 4 to 6.

The OLED substrate of FIG. 4 has a tandem structure in which the first electrode 10, the blue first emission unit 31B, the blue second emission unit 32B, a green third emission unit 33G, and the second electrode 50 are vertically stacked in this order.

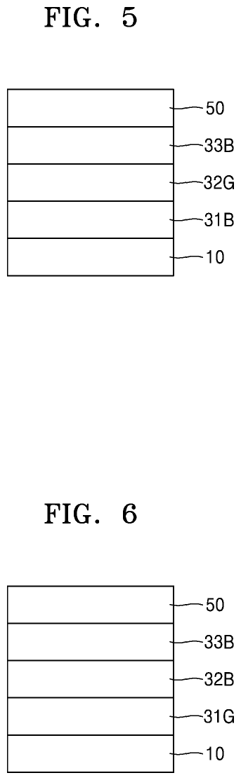

The OLED substrate of FIG. 5 has a tandem structure in which the first electrode 10, the blue first emission unit 31B, the green second emission unit 32G, a blue third emission unit 33B, and the second electrode 50 are vertically stacked in this order.

The OLED substrate of FIG. 6 has a tandem structure in which the first electrode 10, the green first emission unit 31G, the blue second emission unit 32B, the blue third emission unit 33B, and the second electrode 50 are vertically stacked in this order.

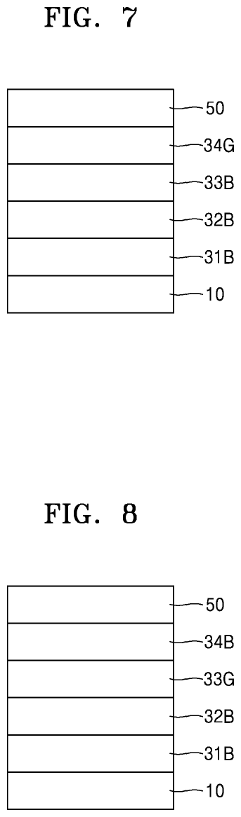

The OLED substrate may include three blue emission units and one green emission unit, as illustrated in FIGS. 7 to 10.

The OLED substrate of FIG. 7 has a tandem structure in which the first electrode 10, the blue first emission unit 31B, the blue second emission unit 32B, the blue third emission unit 33B, a green fourth emission unit 34G, and the second electrode 50 are vertically stacked in this order.

The OLED substrate of FIG. 8 has a tandem structure in which the first electrode 10, the blue first emission unit 31B, the blue second emission unit 32B, the green third emission unit 33G, a blue fourth emission unit 34B, and the second electrode 50 are vertically stacked in this order.

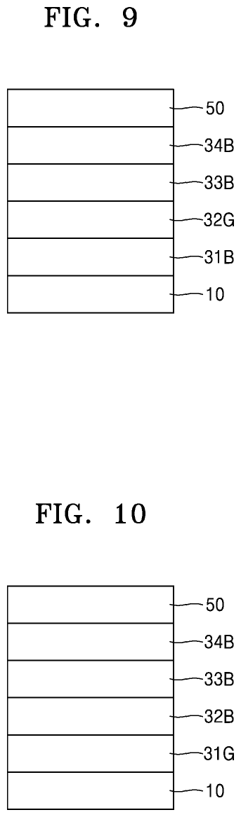

The OLED substrate of FIG. 9 has a tandem structure in which the first electrode 10, the blue first emission unit 31B, the green second emission unit 32G, the blue third emission unit 33B, the blue fourth emission unit 34B and the second electrode 50 are vertically stacked in this order.

The OLED substrate of FIG. 10 has a tandem structure in which the first electrode 10, the green first emission unit 31G, the blue second emission unit 32B, the blue third emission unit 33B, the blue fourth emission unit 34B, and the second electrode 50 are vertically stacked in this order.

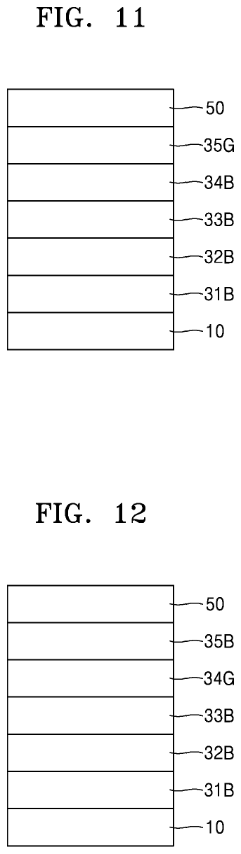

The OLED substrate may include four blue emission units and one green emission unit, as illustrated in FIGS. 11 to 15.

The OLED substrate of FIG. 11 has a tandem structure in which the first electrode 10, the blue first emission unit 31B, the blue second emission unit 32B, the blue third emission unit 33B, the blue fourth emission unit 34B, a green fifth emission unit 35G, and the second electrode 50 are vertically stacked in this order.

The OLED substrate of FIG. 12 has a tandem structure in which the first electrode 10, the blue first emission unit 31B, the blue second emission unit 32B, a blue third emission unit 33B, a green fourth emission unit 34G, a blue fifth emission unit 35B, and the second electrode 50 are vertically stacked in this order.

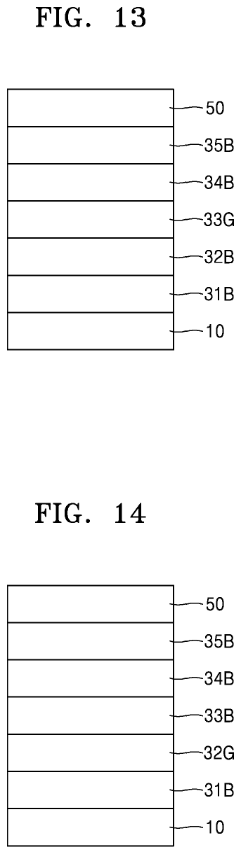

The OLED substrate of FIG. 13 has a tandem structure in which the first electrode 10, the blue first emission unit 31B, the blue second emission unit 32B, the green third emission unit 33G, the blue fourth emission unit 34B, the blue fifth emission unit 35B, and the second electrode 50 are vertically stacked in this order.

The OLED substrate of FIG. 14 has a tandem structure in which the first electrode 10, the blue first emission unit 31B, the green second emission unit 32G, the blue third emission unit 33B, the blue fourth emission unit 34B, the blue fifth emission unit 35B, and the second electrode 50 are vertically stacked in this order.

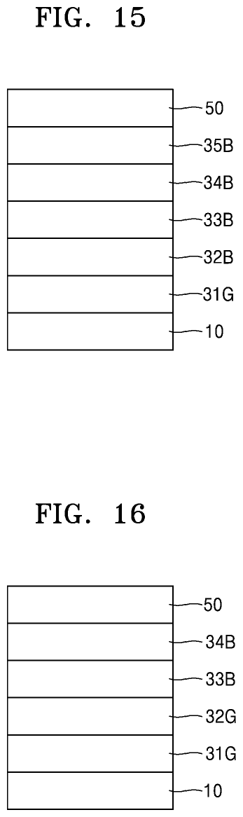

The OLED substrate of FIG. 15 has a tandem structure in which the first electrode 10, the green first emission unit 31G, the blue second emission unit 32B, the blue third emission unit 33B, the blue fourth emission unit 34B, the blue fifth emission unit 35B, and the second electrode 50 are vertically stacked in this order.

The OLED substrate may include two blue emission units and two green emission units, as illustrated in FIGS. 16 to 19.

The OLED substrate of FIG. 16 has a tandem structure in which the first electrode 10, the green first emission unit 31G, the green second emission unit 32G, the blue third emission unit 33B, the blue fourth emission unit 34B, and the second electrode 50 are vertically stacked in this order.

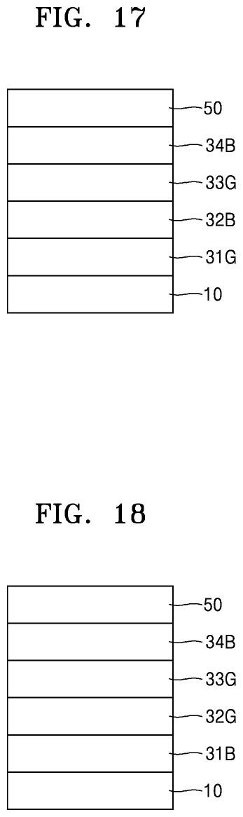

The OLED substrate of FIG. 17 has a tandem structure in which the first electrode 10, the green first emission unit 31G, the blue second emission unit 32B, the green third emission unit 33G, the blue fourth emission unit 34B, and the second electrode 50 are vertically stacked in this order.

The OLED substrate of FIG. 18 has a tandem structure in which the first electrode 10, the blue first emission unit 31B, the green second emission unit 32G, the green third emission unit 33G, the blue fourth emission unit 34B, and the second electrode 50 are vertically stacked in this order.

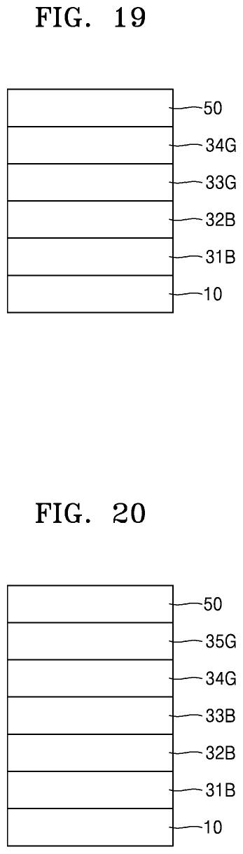

The OLED substrate of FIG. 19 has a tandem structure in which the first electrode 10, the blue first emission unit 31B, the blue second emission unit 32B, the green third emission unit 33G, the green fourth emission unit 34G, and the second electrode 50 are vertically stacked in this order.

The OLED substrate may include three blue emission units and two green emission units, as illustrated in FIGS. 20 to 29.

The OLED substrate of FIG. 20 has a tandem structure in which the first electrode 10, the blue first emission unit 31B, the blue second emission unit 32B, the blue third emission unit 33B, the green fourth emission unit 34G, the green fifth emission unit 35G, and the second electrode 50 are vertically stacked in this order.

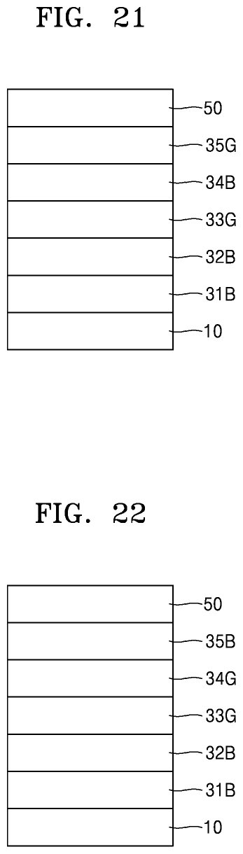

The OLED substrate of FIG. 21 has a tandem structure in which the first electrode 10, the blue first emission unit 31B, the blue second emission unit 32B, the green third emission unit 33G, the blue fourth emission unit 34B, the green fifth emission unit 35G, and the second electrode 50 are vertically stacked in this order.

The OLED substrate of FIG. 22 has a tandem structure in which the first electrode 10, the blue first emission unit 31B, the blue second emission unit 32B, the green third emission unit 33G, the green fourth emission unit 34G, the blue fifth emission unit 35B, and the second electrode 50 are vertically stacked in this order.

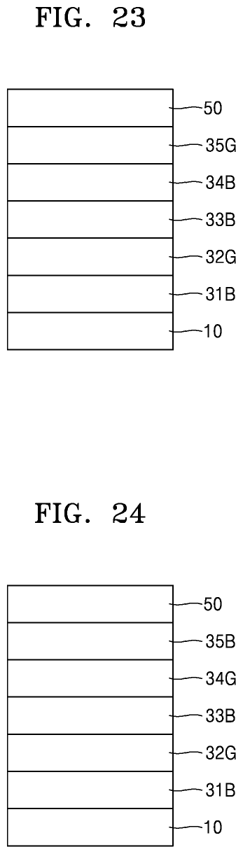

The OLED substrate of FIG. 23 has a tandem structure in which the first electrode 10, the blue first emission unit 31B, the green second emission unit 32G, the blue third emission unit 33B, the blue fourth emission unit 34B, the green fifth emission unit 35G, and the second electrode 50 are vertically stacked in this order.

The OLED substrate of FIG. 24 has a tandem structure in which the first electrode 10, the blue first emission unit 31B, the green second emission unit 32G, the blue third emission unit 33B, the green fourth emission unit 34G, the blue fifth emission unit 35B, and the second electrode 50 are vertically stacked in this order.

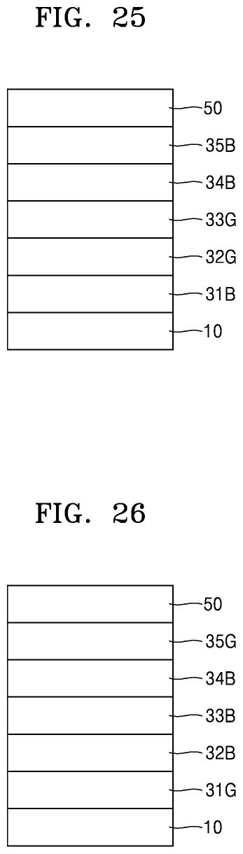

The OLED substrate of FIG. 25 has a tandem structure in which the first electrode 10, the blue first emission unit 31B, the green second emission unit 32G, the green third emission unit 33G, the blue fourth emission unit 34B, the blue fifth emission unit 35B, and the second electrode 50 are vertically stacked in this order.

The OLED substrate of FIG. 26 has a tandem structure in which the first electrode 10, the green first emission unit 31G, the blue second emission unit 32B, the blue third emission unit 33B, the blue fourth emission unit 34B, the green fifth emission unit 35G, and the second electrode 50 are vertically stacked in this order.

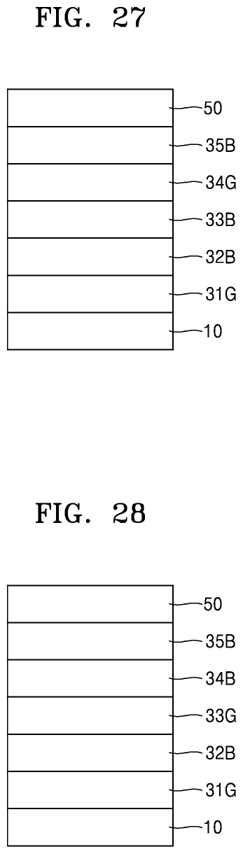

The OLED substrate of FIG. 27 has a tandem structure in which the first electrode 10, the green first emission unit 31G, the blue second emission unit 32B, the blue third emission unit 33B, the green fourth emission unit 34G, the blue fifth emission unit 35B, and the second electrode 50 are vertically stacked in this order.

The OLED substrate of FIG. 28 has a tandem structure in which the first electrode 10, the green first emission unit 31G, the blue second emission unit 32B, the green third emission unit 33G, the blue fourth emission unit 34B, the blue fifth emission unit 35B, and the second electrode 50 are vertically stacked in this order.

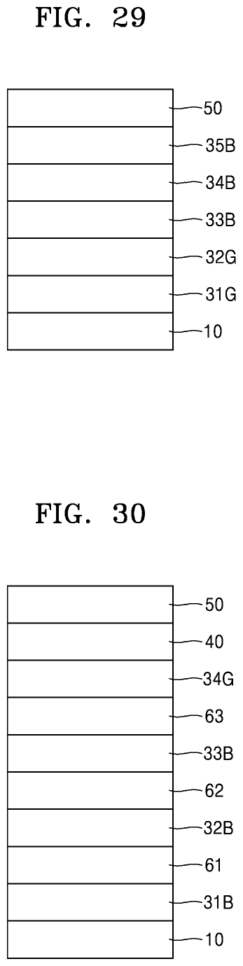

The OLED substrate of FIG. 29 has a tandem structure in which the first electrode 10, the green first emission unit 31G, the green second emission unit 32G, the blue third emission unit 33B, the blue fourth emission unit 34B, the blue fifth emission unit 35B, and the second electrode 50 are vertically stacked in this order.

The OLED substrates of FIGS. 3 to 29 may be understood by referring to the OLED substrate of FIG. 2 except that the number of emission units and/or the emission color has been changed.

The OLED substrate of FIG. 30 has a tandem structure in which the first electrode 10, the blue first emission unit 31B, a first charge generation layer 61, the blue second emission unit 32B, a second charge generation layer 62, the blue third emission unit 33B, a third charge generation layer 63, the green fourth emission unit 34G, an electron transport region 40, and the second electrode 50 are vertically stacked in this order.

Each of the first electrode 10, the blue first emission unit 31B, the blue second emission unit 32B, the blue third emission unit 33B, the green fourth emission unit 34G, and the second electrode 50 of FIG. 30 is the same as described in connection with FIG. 7.

The first charge generation layer 61 may supply charges to the blue first emission unit 31B and/or the blue second emission unit 32B, and the second charge generation layer 62 may supply charges to the blue second emission unit 32B and/or the blue third emission unit 33B, and the third charge generation layer 63 may supply charges to the blue third emission unit 33B and/or the green fourth emission unit 34G. Accordingly, the three blue emission units 31B, 32B, and 33B and one green emission unit 34G may emit light effectively.

The electron transport region 40 may transfer electrons injected from the second electrode 50 to the green fourth emission unit 34G. In one or more embodiments, the electron transport region 40 may include a hole-blocking layer, an electron transport layer, an electron injection layer, or a combination thereof.

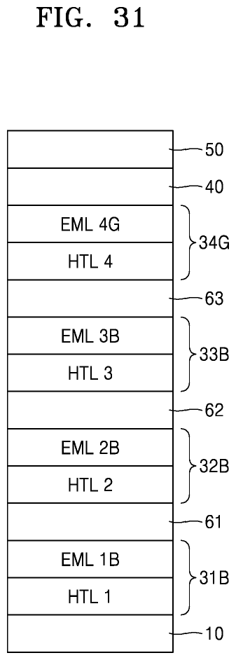

The OLED substrate of FIG. 31 is a diagram illustrating details of the structure of each of the blue first emission unit 31B, the blue second emission unit 32B, the blue third emission unit 33B, and the green fourth emission unit 34G of the OLED substrate of FIG. 30.

The blue first emission unit 31B may include a first hole transport region HTL 1 and a blue first emission layer EML 1B, the blue second emission unit 32B may include a second hole transport region HTL 2 and a blue second emission layer EML 2B, the blue third emission unit 33B may include a third hole transport region HTL 3 and a blue third emission layer EML 3B, and the green fourth emission unit 34G may include a fourth hole transport region HTL 4 and a green fourth emission layer EML 4G.

The first hole transport region HTL 1, the second hole transport region HTL 2, the third hole transport region HTL 3, and the fourth hole transport region HTL 4 may transfer holes to the blue first emission layer EML 1B, the blue second emission layer EML 2B, the blue third emission layer EML 3B, and the green fourth emission layer EML 4G, respectively. Each of the first hole transport region HTL 1, the second hole transport region HTL 2, the third hole transport region HTL 3, and the fourth hole transport region HTL 4 may include a hole injection layer, a hole transport layer, an electron-blocking layer, a buffer layer, or a combination thereof.

The blue first emission layer EML 1B, the blue second emission layer EML 2B, and the blue third emission layer EML 3B may include the blue luminescent compound as described above, and the green fourth emission layer EML 4G may include a mixture of the first compound and the second compound as described herein.

The green fourth emission layer EML 4G may include a host in addition to the mixture of the first compound and the second compound. The host may include a hole-transporting host, an electron-transporting host, a bipolar host, or a combination thereof.

In one or more embodiments, the green fourth emission layer EML 4G may be formed by i) co-depositing a first compound, a second compound, and a host or ii) a soluble process in which a solution including a first compound, a second compound, and a host is provided, and heat treatment is performed.

Although not shown, the OLED substrate of FIGS. 2 to 6 and 8 to 29 may be variously changed with reference to the first charge generation layer 61, the second charge generation layer 62 and/or the third charge generation layer 63 of FIG. 30 and the first hole transport region HTL 1, the second hole transport region HTL 2, the third hole transport region HTL 3, the fourth hole transport region HTL 4, the blue first emission layer EML 1B, the blue second emission layer EML 2B, the blue third emission layer EML 3B, and/or the green fourth emission layer EML 4G of FIG. 31.

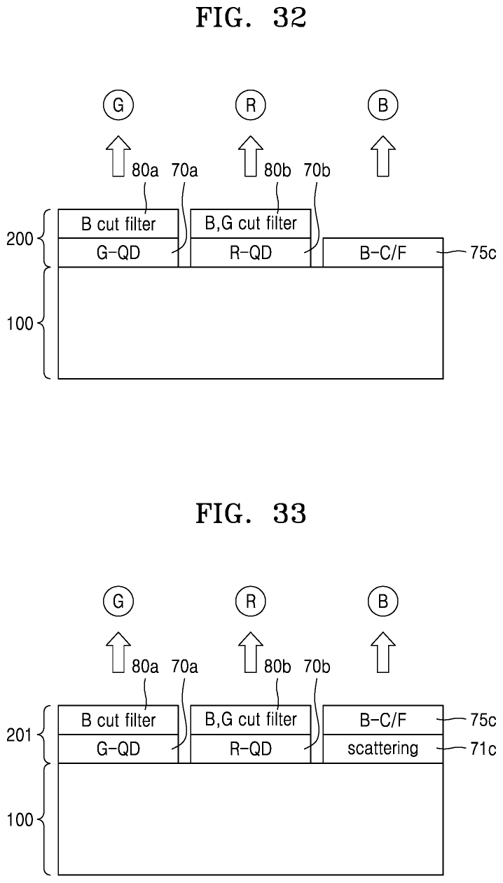

### Description of FIG. 32

FIG. 32 is a cross-sectional view illustrating a light-emitting device according to one or more embodiments.

The light-emitting device of FIG. 32 may include an OLED substrate 100 and a color control unit 200.

The OLED substrate 100 may be the same as described above (for example, with reference to FIGS. 2 to 31).

The color control unit 200 may include a first color control element 70a including a first quantum dot (green light emitting quantum dot (G-QD)) for green conversion, a second color control element 70b including a second quantum dot (red light emitting quantum dot (R-QD)) for red conversion, and a third color control element 75c for blue expression. The color control element is not limited to including a quantum dot. In one or more embodiments, an inorganic material, an organic material, or a combination thereof that absorbs blue light or/and green light and converts the same to green light or red light, may be used as the color control element. In one or more embodiments, the color control unit 200 may further include a first color filter 80a located on the first color control element 70a and a second color filter 80b located on the second color control element 70b.

The first color control element 70a may be a green-QD-containing layer, and may convert light generated from the OLED substrate 100 into green light G. The second color control element 70b may be a red-QD containing layer and may convert light generated from the OLED substrate 100 to red light R. Accordingly, the first color control element 70a may be referred to as a first color conversion element, and the second color control element 70b may be referred to as a second color conversion element. The color conversion element may include a resin material, a plurality of quantum dots, and a light scattering agent. The resin material may include, for example, a photoresist (PR) material. In one or more embodiments, the third color control element 75c may be a color filter that optionally allows the blue (B) wavelength region of the light generated from the OLED substrate 100 to pass therethrough. In other words, the third color control element 75c may be a blue-color filter (C/F or CF). In this case, the third color control element 75c may be an absorption type color filter including a specific pigment(s) or quantum dot(s). The absorption type color filter may absorb light of wavelength band except light of the target wavelength band.

The first color filter 80a may cut the remaining blue region wavelength of the light that has passed through the first color control element 70a. The second color filter 80b may cut the remaining blue and green regions wavelength of the light that has passed through the second color control element 70b. The first color filter 80a may be referred to as a blue-cut filter, and the second color filter 80b may be referred to as a blue and green-cut filter. Accordingly, color-controlling/filtering characteristics may be improved by the first color filter 80a and the second color filter 80b. Although not illustrated, a separate optical film may be additionally located on the third color control element 75c. Full colors of RGB may be realized by using the color control unit 200. Herein, the arrangement order or arrangement method of the RGB subpixels is an example, and may be variously changed.

The first quantum dot that may be included in the first color control element 70a may be green-QD, and the second quantum dot that may be included in the second color control element 70b may be red-QD. A quantum dot refers to a semiconductor particle of a small sphere of nanometer (nm) size or a similar shape, and may have a size (diameter) of about several nm to several tens of nm. A quantum dot may have a monolithic structure or a core-shell structure, and in the case of a core-shell structure, the quantum dot may have a single shell structure or a multi-shell structure. For example, a quantum dot may have a core portion (center) including a first semiconductor and a shell portion including a second semiconductor. Here, a material for the core portion (center) may be cadmium selenide (CdSe), cadmium telluride (CdTe), or cadmium sulfide (CdS), and a material for the shell portion may be zinc sulfide (ZnS). Also, a non-cadmium-based quantum dot (QD) may be used. That is, various materials not including cadmium (Cd) may be applied to the quantum dot. However, the materials specifically presented here are exemplary, and other various materials may be applied to the quantum dot. For example, the quantum dot may include at least one of a group Il-VI semiconductor, a group Ill-V semiconductor, a group IV-VI semiconductor, a group IV semiconductor, or combination thereof.

Because quantum dots are very small in size, quantum dots may exhibit a quantum confinement effect. When a particle is very small, electrons in the particle form a discontinuous energy state by the outer wall of the particle. As the size of the space inside the particle is small, the energy state of the electrons is relatively high, and the energy band gap increases. This effect is called as the quantum confinement effect. According to such a quantum confinement effect, when light such as ultraviolet rays or visible rays is incident on a quantum dot, light of various wavelengths may be generated. The wavelength of light generated from a quantum dot may be determined by the size, material, and/or structure of the particle (quantum dot). Specifically, when light with a wavelength greater than the energy band width is incident on the quantum dot, the quantum dot may be excited by absorbing the energy of the light and may transit to a ground state while emitting light of a specific wavelength. In this case, as the size of the quantum dot (or, the core portion of the quantum dot) is smaller, light of a relatively short wavelength, for example, bluish light or greenish light may be generated, and as the size of the quantum dot (or, the core portion of the quantum dot) is larger, light of a relatively long wavelength, for example, reddish light may be generated. Therefore, light of various colors may be realized according to the size of the quantum dot (or the core portion of the quantum dot). Quantum dot particles that may emit greenish light may be referred to as green light quantum dot particles, and quantum dot particles that may emit reddish light may be referred to as red light quantum dot particles. For example, green light quantum dot particles (or the core portion thereof) may be particles having a particle width (diameter) of about 2 nm to about 3 nm, and red light quantum dot particles (or the core portion thereof) may be particles having a particle width (diameter) of about 5 nm to about 6 nm. The emission wavelength may be controlled not only by the size (diameter) of the quantum dot but also by the material and structure.

Since the first color control element 70a may be regarded as a kind of color filter that converts colors using quantum dots, the first color control element 70a may be referred to as a “first QD color filter”. Similarly, the second color control element 70b may be referred to as a “second QD color filter”.

The first color filter 80a and the second color filter 80b of a cut-off filter type may be formed in, for example, a distributed Bragg reflector (DBR) structure. A DBR structure that passes or reflects only the desired wavelength band may be created by repeatedly stacking two material layers (dielectrics) having different refractive indices and adjusting the thickness and the number of layers to be stacked of the material layers. The DBR structure may be applied to the first color filter 80a and the second color filter 80b. For example, a SiO₂ layer and a TiO₂ layer may be repeatedly stacked under λ/4 condition (here, “A” represents a wavelength of light), and the thickness and the number of layers to be stacked may be controlled to increase a reflectance and a transmittance of a desired wavelength band. As the DBR structure is well known, the detailed descriptions thereof are omitted herein. In addition, at least one of the first color filter 80a and the second color filter 80b may have a structure other than the DBR structure, for example, a high-contrast grating (HCG) structure.

### Description of FIG. 33

FIG. 33 is a cross-sectional view illustrating a light-emitting device according to one or more embodiments.

The light-emitting device of FIG. 33 may include the OLED substrate 100 and a color control unit 201.

The OLED substrate 100 may be the same as described above (for example, with reference to FIGS. 2 to 31).

The color control unit 201 of FIG. 33 is the same as the color control unit 200 of FIG. 32 except that a light scattering element 71c located between the third color control element 75c and the OLED substrate 100 is added.

The light scattering element 71c may include a resin material and a light scattering agent. In this embodiment, the resin material may include a photoresist (PR) material. The light scattering agent may include, for example, titanium oxide (TiO₂). The first color control element 70a and the second color control element 70b may each include a light scattering agent. Accordingly, by positioning the light scattering element 71c under the third color control element 75c, the impression of colors may be balanced. In other words, change in visibility in a RGB region may be reduced.

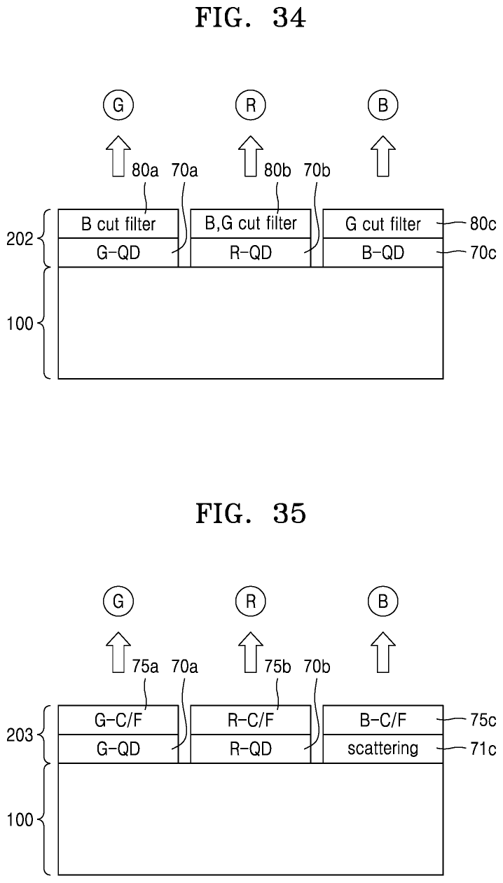

### Description of FIG. 34

FIG. 34 is a cross-sectional view illustrating a light-emitting device according to one or more embodiments,

The light-emitting device of FIG. 34 may include the OLED substrate 100 and a color control unit 202.

The OLED substrate 100 may be the same as described above (for example, with reference to FIGS. 2 to 31).

The color control unit 202 of FIG. 34 is the same as the color control unit 200 of FIG. 32 except that a blue-QD (blue light-emitting quantum dot)-containing layer as the third color control element 70c is used instead of the blue-color filter (B-C/F) as the third color control element 75c, and a third color filter 80c disposed on the third color control element 75c may be further included. The third color filter 80c may optionally be included.

The third color control element 70c may convert the light generated from the OLED substrate 100 into blue light B. Accordingly, the third color control element 70c may be referred to as a third color conversion element. The third color control element 70c may include a resin material, quantum dots, and a light scattering agent. The third color filter 80c may cut the remaining green region wavelength of the light that has passed through the third color control element 70c. That is, the third color filter 80c may be a green-cut filter.

### Description of FIG. 35

FIG. 35 is a cross-sectional view illustrating a light-emitting device according to one or more embodiments;

The light-emitting device of FIG. 35 may include the OLED substrate 100 and a color control unit 203.

The OLED substrate 100 may be the same as described above (for example, with reference to FIGS. 2 to 31).

The color control unit 203 of FIG. 35 is the same as the color control unit 201 of FIG. 33, except that a first color filter 75a and a second color filter 75b are used instead of the first color filter 80a and the second color filter 80b that are of a cut-off filter type, respectively.

An absorption-type green-color filter (G-C/F) may be used as the first color filter 75a, and an absorption-type red-color filter (R-C/F) may be used as the second color filter 75b. The green-color filter 75a may selectively transmit light in the green wavelength region and absorb light in the other wavelength region. Similarly, the red-color filter 75b may selectively transmit light in the red wavelength region and absorb light in the other wavelength region. The color control unit 203 of the present embodiment uses absorption type color filters 75a, 75b, and 75c respectively for the R-subpixel, G-subpixel and B-subpixel regions. In this embodiment, the third color control element 70c containing the blue-QD in FIG. 34 may be used instead of the light scattering element 71c.

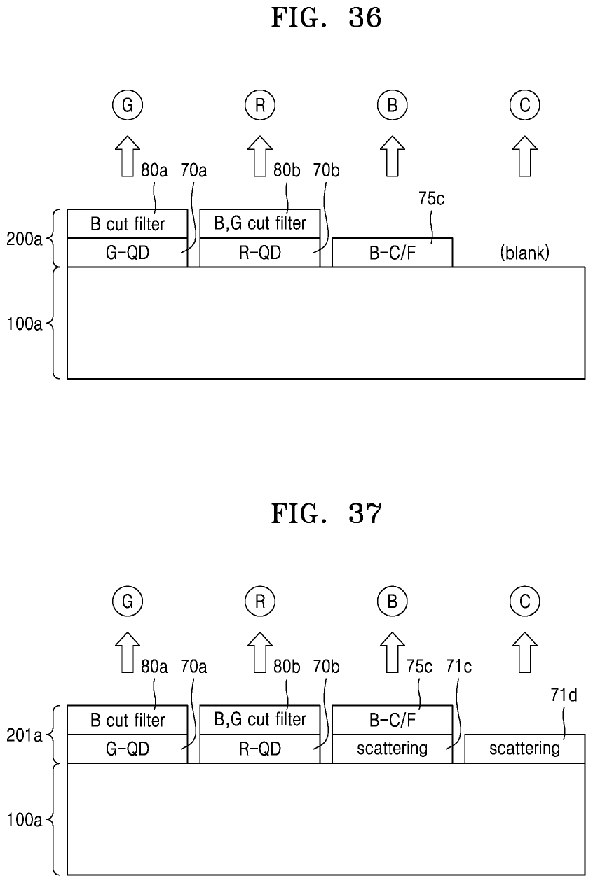

### Description of FIGS. 36 to 39

In one or more embodiments, the light-emitting device may further include a fourth sub-pixel, in addition to a R-sub-pixel (first sub-pixel), a G-sub-pixel (second sub-pixel), and a B-sub-pixel (third sub-pixel). The fourth sub-pixel may be configured to exhibit a color (a fourth color) other than R, G, and B. The other color (fourth color) may be, for example, cyan (C). Embodiments of the light-emitting device further including the fourth sub-pixel area are illustrated in FIGS. 36 to 39. In FIGS. 36 to 39, 100a denotes an OLED substrate, and 200a, 201a, 202a, and 203a denote color control units.

Referring to FIG. 36, the present embodiment is similar to the configuration described in connection with FIG. 32, except that a portion of the OLED substrate 100a is a blank region. The blank region may correspond to the fourth sub-pixel region, and cyan (C) color may be exhibited from the blank region.

Referring to FIG. 37, the present embodiment is similar to the configuration described in connection with FIG. 33, except that a light scattering element 71d may be further included in the fourth sub-pixel area of the OLED substrate 100a. The light scattering element 71c provided under the third color control element 75c is a first light scattering element, and the light scattering element 71d provided in the fourth sub-pixel area may be referred to as a second light scattering element. The first light scattering element 71c and the second light scattering element 71d may have the same or similar material composition.

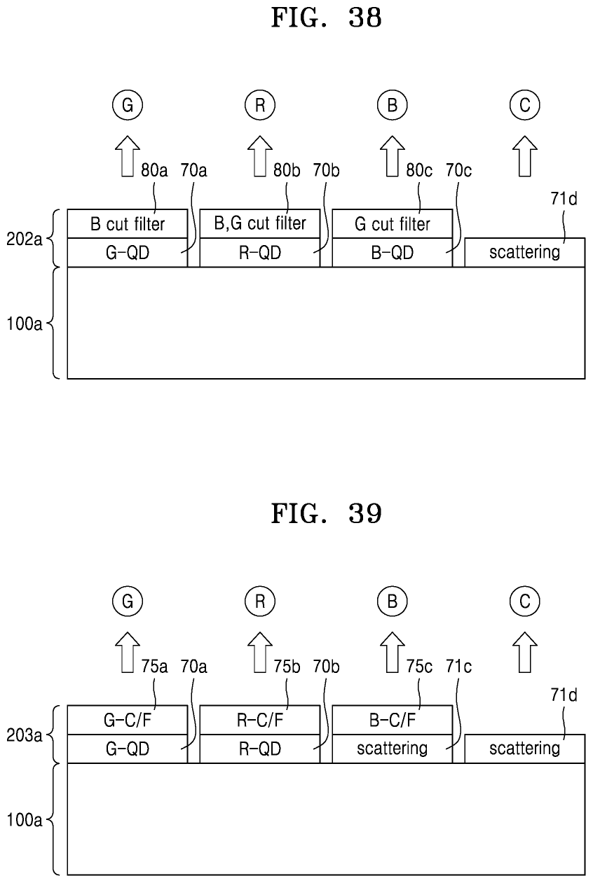

Referring to FIG. 38, the present embodiment is similar to the configuration described in connection with FIG. 34, except that a light scattering element 71d may be further included in the fourth sub-pixel area of the OLED substrate 100a.

Referring to FIG. 39, the present embodiment is similar to the configuration described in connection with FIG. 35, except that the light scattering element 71d may be further included in the fourth sub-pixel area of the OLED substrate 100a.

In the embodiments illustrated in FIGS. 36 to 39, the arrangement order and method of the R-subpixel (the first subpixel), the G-subpixel (the second subpixel), the B-subpixel (the third subpixel), and the C-subpixel (the fourth subpixel) are illustrative only, and various alterations may be made. In some embodiments, the R, G, B, and C subpixel regions may be arranged such that a square shape matrix form may be formed when viewed from a top view. In addition, the color exhibited in the C-subpixel (the fourth subpixel) region may be any other color other than cyan (C).

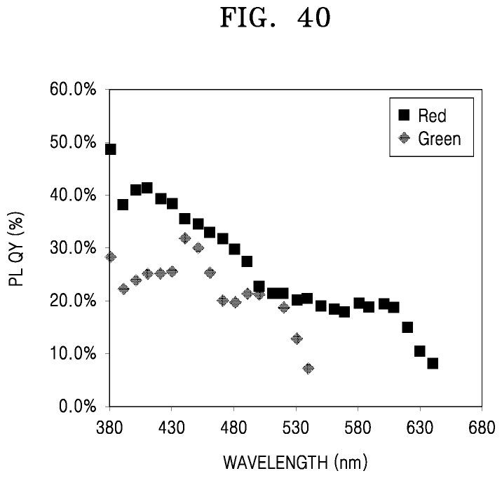

### Description of FIG. 40

FIG. 40 shows a graph of a PL quantum yield (%) according to the wavelength (nm) of a green-QD containing color conversion element and a red-QD containing color conversion element which may be applicable to a light-emitting device according to one or more embodiments.

Referring to FIG. 40, it can be seen that the green-QD containing color conversion element provides the PL quantum yield up to approximately the green wavelength region, and the red-QD containing color conversion element provides the PL quantum yield up to approximately the red wavelength region. The green-QD containing color conversion element and the red-QD containing color conversion element may be applicable to the first color control element 70a and the second color control element 70b of FIGS. 32 to 39, respectively.

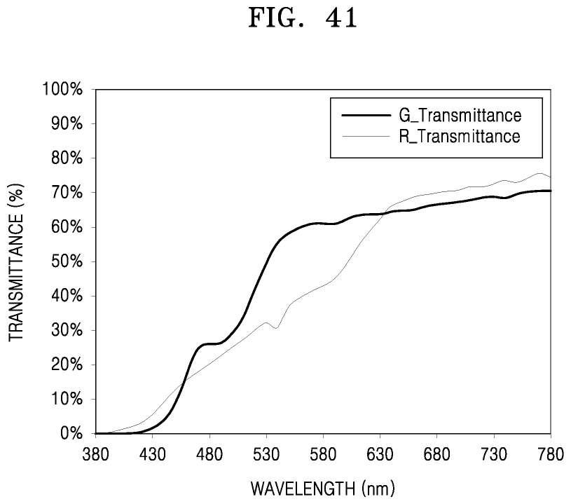

### Description of FIG. 41

FIG. 41 shows a graph of transmittance (%) according to the wavelength of a green-QD containing color conversion element and a red-QD containing color conversion element which may be applicable to a light-emitting device according to one or more embodiments.

Referring to FIG. 41, it can be seen that the green-QD containing color conversion element provides the transmittance from a wavelength corresponding to approximately in the green region, and the red-QD containing color conversion element provides the transmittance from a wavelength corresponding to approximately in the red region.

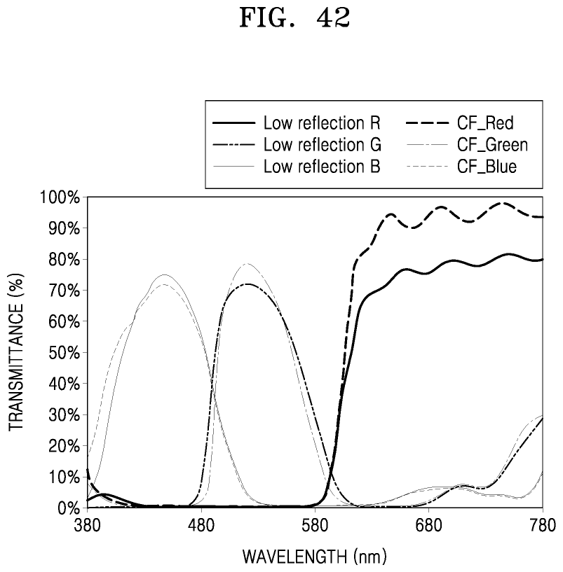

### Description of FIG. 42

FIG. 42 shows a graph of transmittance (%) according to wavelength of an absorption type color filter that may be applicable to a light-emitting device according to one or more embodiments. Results for absorption type red-color filter (CF-Red), absorption type green-color filter (CF-Green) and absorption type blue-color filter (CF-Blue) are included. In addition, the results for absorption type low reflection red-color filter (low reflection R), absorption type low reflection green-color filter (low reflection G) and absorption type low reflection blue-color filter (low reflection B) are also included. The term “low reflection” in the absorption type low reflection red-color filter refers to the case where the reflectance is relatively lower than that of the absorption type red-color filter. This description is also applicable to the low reflection green-color filter and the low reflection blue-color filter. By controlling the configuration of the color filter, the reflectance and transmittance thereof may be appropriately adjusted. The absorption type low reflection green-color filter, the absorption type low reflection red-color filter, and the absorption type low reflection blue-color filter may also be applied to the first color filter 75a, the second color filter 75b and the third color control element 75c, respectively. By using an absorption type low-reflection color filter, the reflectivity on a panel may be reduced, so that the contrast ratio in the bright room can be increased without a circular polarizer.

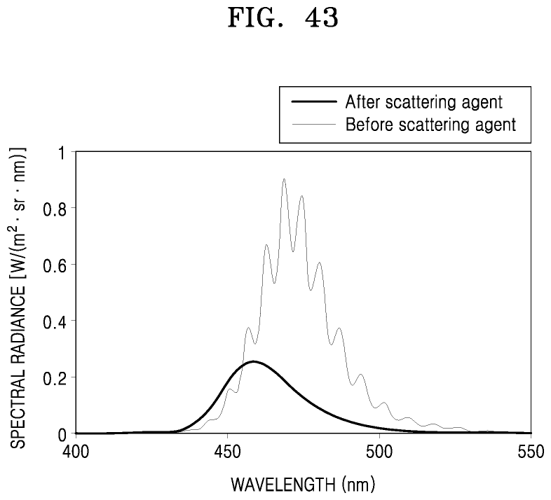

### Description of FIG. 43

FIG. 43 shows a graph showing a difference in spectral radiance when a light scattering agent is applied to blue light and when no light scattering agent is applied.

Referring to FIG. 43, when a light scattering agent is not applied (before the scattering agent is used), it can be seen that the light is not well dispersed and a number of peaks are generated. When a light scattering agent is applied (after the scattering agent is used), it can be seen that one peak with a relatively smooth curve appears because the light is well dispersed.

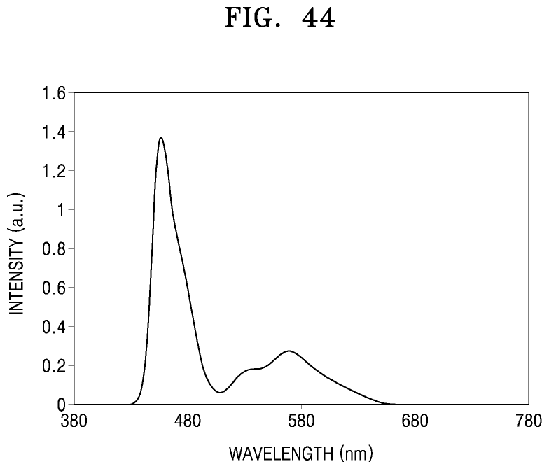

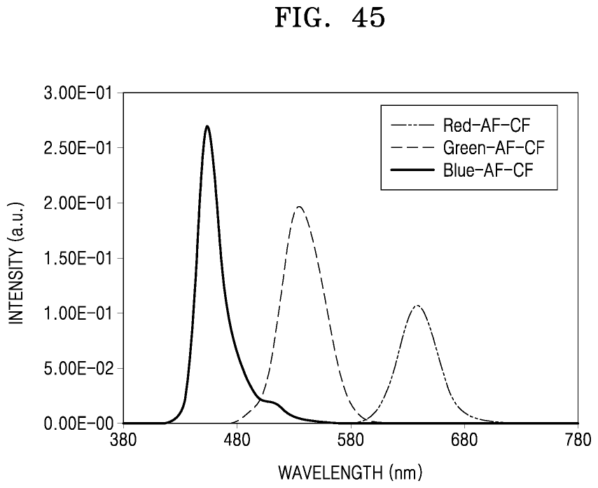

### Description of Table 1, and FIGS. 44 and 45

OLED substrates A, B, C, 1 and 2, each having the structure illustrated in FIG. 31, were fabricated. OLED substrates A, B, C, 1 and 2 are identical to each other except that, for each OLED substrate, the dopant compound(s) included in the EML4G of the green fourth emission unit 34G is as shown in Table 1. Each of Ir1, Ir2 and Pt1 in Table 1 emit a green light. Then, the luminescence efficiency (candela per ampere, cd/A) and lifespan (LT₉₅, hr, relative %) of each of OLED substrates A, B, C, 1 and 2 were measured using a current-voltmeter (Keithley 2400) and a luminance meter (Minolta Cs-1000A), under the luminance conditions described in in Table 1. Results thereof are shown as a relative value (%) in Table 1. The Lifespan (LT₉₅) refers to a time that is taken for the luminance to become 95% with respect to the initial luminance of 100%. In Table 1, the number in parentheses describes the doping concentration of the corresponding dopant relative to 100 wt % of EML4G, and the host of EML4G is a mixture of Compound H-H1 and Compound H-H2 (weight ratio=1:1). EML4G is consisted of the dopant compound(s) and the hosts.

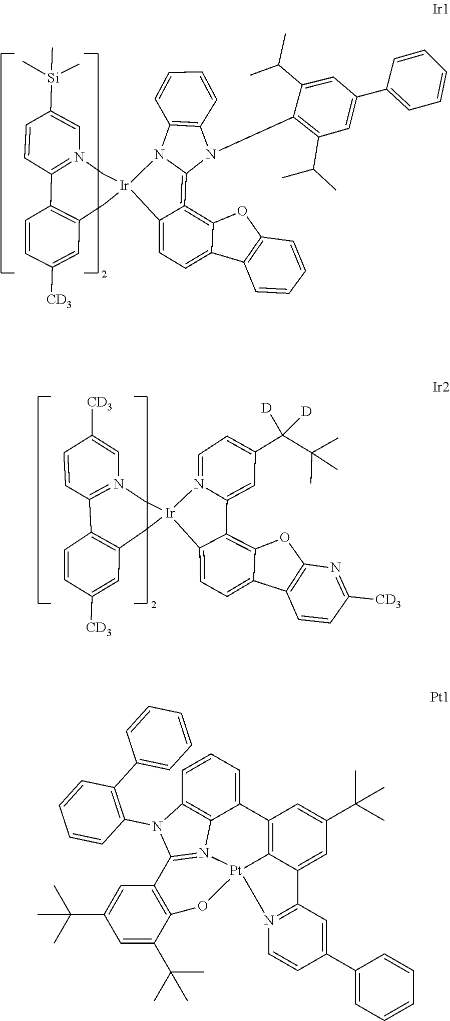

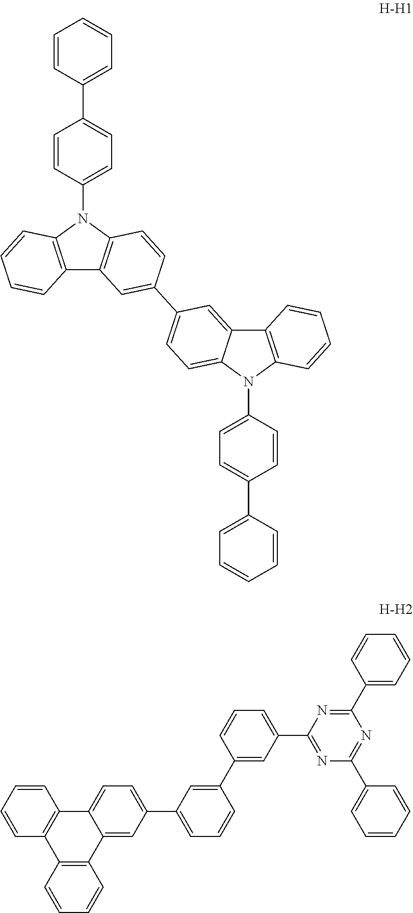 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccccc3)nc(-c3cccc(-c4cccc(-c5ccc6c7ccccc7c7ccccc7c6c5)c4)c3)n2)cc1]

TABLE 1

| | | | Luminescence efficiency | | Lifespan (LT₉₅) | |
|---|---|---|---|---|---|---|
| | | | (Relative value, %) | | (Relative value, %) | |
| | Dopant included | | at 10,000 | at 30,000 | at 10,000 | at 30,000 |
| | in EML4G | | cd/m² | cd/m² | cd/m² | cd/m² |
| OLED | Ir1 | | 100 | 95 | 100 | 19 |
| substrate A | (5 wt %) | | | | | |
| OLED | Ir2 | | 95 | 90 | 90 | 17 |
| substrate B | (5 wt %) | | | | | |
| OLED | Pt1 | | 100 | 93 | 80 | 15 |
| substrate C | (5 wt %) | | | | | |
| OLED | Ir1 | Ir2 | 100 | 96 | 210 | 50 |
| substrate 1 | (5 wt %) | (4 wt %) | | | | |
| OLED | Pt1 | Ir1 | 102 | 99 | 250 | 60 |
| substrate 2 | (5 wt %) | (5 wt %) | | | | |

From Table 1, It can be seen that the luminescence efficiency and lifespan characteristics of OLED substrate 1 are improved compared to the luminescence efficiency and lifespan (at high luminance) of OLED substrates A and B, and the luminescence efficiency and lifespan characteristics of OLED substrate 2 are improved compared to the luminescence efficiency and lifespan characteristics of OLED substrates A and C.

FIG. 44 shows a graph of the EL spectrum of OLED substrate 2. Referring to FIG. 44, it can be seen that OLED substrate 2 emits light in which blue light is mixed with green light.

Subsequently, Light Emitting Device 1 having the structure illustrated in FIG. 35 was manufactured including: OLED substrate 2 as the OLED substrate 100;

i) a green-QD containing color conversion element and a red-QD containing color conversion element that can provide the PL quantum yield according to the wavelength illustrated in FIG. 40 and the transmittance according to the wavelength illustrated in FIG. 41, respectively as the first color control element 70a including a first quantum dot (QD) for green conversion and the second color control element 70b including a second quantum dot for red conversion;

ii) three absorption type color filters showing the transmittance according to the wavelength of the absorption type red-color filter (CF-Red), the absorption type green-color filter (CF-Green), and the absorption type blue-color filter (CF-Blue), respectively as three absorption type color filters 75a, 75b, and 75c, respectively; and

iii) the color control unit 203 including the light scattering element that can provide the spectral radiance difference illustrated in FIG. 43, as the light scattering element 71c.

FIG. 45 shows a graph of the PL spectrum of the Light Emitting Device 1. As illustrated in FIG. 45, it can be seen that the blue light and green light emitted from OLED substrate 2 are effectively emitted in the form of red light, green light, and blue light after passing through the color control unit 203.

The light-emitting devices according to the embodiments described above may be applicable to various electronic apparatuses such as display apparatus. For example, the light emitting devices may be usefully applied to small-sized electronic devices such as portable devices and wearable devices, and medium- to large-sized electronic devices such as home appliances.

The term “C₁-C₆₀ alkyl group” as used herein refers to a linear or branched saturated aliphatic hydrocarbons monovalent group having 1 to 60 carbon atoms, and the term “C₁-C₆₀ alkylene group” as used herein refers to a divalent group having the same structure as the C₁-C₆₀ alkyl group.

Examples of the C₁-C₆₀ alkyl group, the C₁-C₂₀ alkyl group, and/or the C₁-C₁₀ alkyl group are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, or a tert-decyl group, each unsubstituted or substituted with a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, or a combination thereof. For example, Formula 9-33 is a branched C alkyl group, for example, a tert-butyl group that is substituted with two methyl groups.

The term “C₁-C₆₀ alkoxy group” as used herein refers to a monovalent group represented by —OA₁₀₁ (wherein A₁₀₁ is the C₁-C₆₀ alkyl group), and examples thereof are a methoxy group, an ethoxy group, a propoxy group, a butoxy group, and a pentoxy group.

The term “C₁-C₆ alkylthio group” as used herein refers to a monovalent group represented by —SA₁₀₁ (wherein A₁₀₁ is the C₁-C₆₀ alkyl group).

The term “C₂-C₆₀ alkenyl group” as used herein refers to a hydrocarbon group formed by substituting at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by substituting at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon cyclic group having 3 to 10 carbon atoms, and the term “C₃-C₁₀ cycloalkylene group” as used herein refers to a divalent group having the same structure as the C₃-C₁₀ cycloalkyl group.

Examples of the C₃-C₁₀ cycloalkyl group are a cyclopropyl group, a cyclobutyl group, a cyclopentyl, cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group.

The term “C₁-C₁₀ heterocycloalkyl group” as used herein refers to a monovalent saturated cyclic group that includes at least one heteroatom selected from N, O, P, Si, S, Se, Ge, and B as a ring-forming atom and 1 to 10 carbon atoms, and the term “C₁-C₁₀ heterocycloalkylene group” as used herein refers to a divalent group having the same structure as the C₁-C₁₀ heterocycloalkyl group.

Examples of the C₁-C₁₀ heterocycloalkyl group are a silolanyl group, a silinanyl group, tetrahydrofuranyl group, a tetrahydro-2H-pyranyl group, and a tetrahydrothiophenyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, S, Se, Ge, and B as a ring-forming atom, 1 to 10 carbon atoms, and at least one double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₇-C₆₀ alkyl aryl group” as used herein refers to a C₆-C₆₀ aryl group substituted with at least one C₁-C₆₀ alkyl group. The term “C₇-C₆₀ aryl alkyl group” as used herein refers to a C₁-C₆₀ alkyl group substituted with at least one C₆-C₆₀ aryl group.

The term “C₁-C₆₀ heteroaryl group” as used herein refers to a monovalent group that includes at least one heteroatom selected from N, O, P, Si, S, Se, Ge, and B as a ring-forming atom and a cyclic aromatic system having 1 to 60 carbon atoms, and the term “C₁-C₆ heteroarylene group” as used herein refers to a divalent group that includes at least one heteroatom selected from N, O, P, Si, S, Se, Ge, and B as a ring-forming atom and a carbocyclic aromatic system having 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₂-C₆₀ alkyl heteroaryl group” as used herein refers to a C₁-C₆₀ heteroaryl group substituted with at least one C₁-C₆₀ alkyl group. The term “C₂-C₆₀ heteroaryl alkyl group” as used herein refers to a C₁-C₆₀ alkyl group substituted with at least one C₁-C₆₀ heteroaryl group.

The term “C₆-C₆₀ aryloxy group” as used herein indicates —OA₁₀₂ (wherein A₁₀₂ indicates the C₆-C₆₀ aryl group), and the term “C₆-C₆₀ arylthio group” as used herein indicates —SA₁₀₃ (wherein A₁₀₃ indicates the C₆-C₆₀ aryl group).

The term “C₁-C₆ heteroaryloxy group” as used herein indicates —OA₁₀₂, (wherein A₁₀₂, indicates the C₁-C₆₀ heteroaryl group), and the term “C₁-C₆ heteroarylthio group” as used herein indicates —SA₁₀₃ (wherein A₁₀₃, indicates the C₁-C₆₀ heteroaryl group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, at least one heteroatom selected from N, O, P, Si, S, Se, Ge, and B, other than carbon atoms, as a ring-forming atom, and no aromaticity in its entire molecular structure. Examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group described above.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group. Examples of the “C₅-C₃₀ carbocyclic group (unsubstituted or substituted with at least one R₁₀ₐ)” used herein are an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, and a fluorene group (each unsubstituted or substituted with at least one R₁₀ₐ).

The term “C₁-C₃₀ heterocyclic group” as used herein refers to a saturated or unsaturated cyclic group having, as a ring-forming atom, at least one heteroatom selected from N, O, P, Si, S, Se, Ge, and B other than 1 to 30 carbon atoms. The C₁-C₃₀ heterocyclic group may be a monocyclic group or a polycyclic group. The “C₁-C₃₀ heterocyclic group (unsubstituted or substituted with at least one R₁₀ₐ)” may be, for example, a thiophene group, a furan group, a pyrrole group, a silole group, borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group (each unsubstituted or substituted with at least one R₁₀ₐ).

Examples of the “C₅-C₃₀ carbocyclic group” and the “C₁-C₃₀ heterocyclic group” as used herein are i) a first ring, ii) a second ring, iii) a condensed ring in which two or more first rings are condensed with each other, iv) a condensed ring in which two or more second rings are condensed with each other, or v) a condensed ring in which at least one first ring is condensed with at least one second ring,

wherein the first ring may be a cyclopentane group, a cyclopentene group, a furan group, a thiophene group, a pyrrole group, a silole group, a borole group, a phosphole group, a germole group, a selenophene group, an oxazole group, an oxadiazole group, an oxatriazole group, a thiazole group, a thiadiazole group, a thiatriazole group, a pyrazole group, an imidazole group, a triazole group, a tetrazole group, or an azasilole group, and

the second ring may be an adamantane group, a norbornane group, a norbornene group, a cyclohexane group, a cyclohexene group, a benzene group, a pyridine group, a pyrimidine group, a pyrazine group, a pyridazine group, or a triazine group.

The terms “fluorinated C₁-C₆₀ alkyl group (or a fluorinated C₁-C₂₀ alkyl group or the like)”, “fluorinated C₃-C₁₀ cycloalkyl group”, “fluorinated C₁-C₁₀ heterocycloalkyl group,” and “fluorinated phenyl group” respectively indicate a C₁-C₆₀ alkyl group (or a C₁-C₂₀ alkyl group or the like), a C₃-C₁₀ cycloalkyl group, a C₁-C₁₀ heterocycloalkyl group, and a phenyl group, each substituted with at least one fluoro group (—F). For example, the term “fluorinated C₁ alkyl group (that is, a fluorinated methyl group)” includes —CF₃, —CF₂H, and —CFH₂. The “fluorinated C₁-C₆₀ alkyl group (or, a fluorinated C₁-C₂₀ alkyl group, or the like)”, “the fluorinated C₃-C₁₀ cycloalkyl group”, “the fluorinated C₁-C₁₀ heterocycloalkyl group”, or “the fluorinated a phenyl group” may be i) a fully fluorinated C₁-C₆₀ alkyl group (or, a fully fluorinated C₁-C₂₀ alkyl group, or the like), a fully fluorinated C₃-C₁₀ cycloalkyl group, a fully fluorinated C₁-C₁₀ heterocycloalkyl group, or a fully fluorinated phenyl group, wherein, in each group, all hydrogen included therein is substituted with a fluoro group, or ii) a partially fluorinated C₁-C₆₀ alkyl group (or, a partially fluorinated C₁-C₂₀ alkyl group, or the like), a partially fluorinated C₃-C₁₀ cycloalkyl group, a partially fluorinated C₁-C₁₀ heterocycloalkyl group, or partially fluorinated phenyl group, wherein, in each group, all hydrogen atoms included therein are not substituted with a fluoro group.

The terms “deuterated C₁-C₆₀ alkyl group (or a deuterated C₁-C₂₀ alkyl group or the like)”, “deuterated C₃-C₁₀ cycloalkyl group”, “deuterated C₁-C₁₀ heterocycloalkyl group,” and “deuterated phenyl group” respectively indicate a C₁-C₆₀ alkyl group (or a C₁-C₂₀alkyl group or the like), a C₃-C₁₀ cycloalkyl group, a C₁-C₁₀ heterocycloalkyl group, and a phenyl group, each substituted with at least one deuterium. For example, the “deuterated C₁ alkyl group (that is, the deuterated methyl group)” may include —CD₃, —CD₂H, and —CDH₂, and examples of the “deuterated C₃-C₁₀ cycloalkyl group” are, for example, Formula 10-501 and the like. The “deuterated C₁-C₆₀ alkyl group (or, the deuterated C₁-C₂₀ alkyl group or the like)”, “the deuterated C₃-C₁₀ cycloalkyl group”, “the deuterated C₁-C₁₀ heterocycloalkyl group”, or “the deuterated phenyl group” may be i) a fully deuterated C₁-C₆₀ alkyl group (or, a fully deuterated C₁-C₂₀ alkyl group or the like), a fully deuterated C₃-C₁₀ cycloalkyl group, a fully deuterated C₁-C₁₀ heterocycloalkyl group, or a fully deuterated phenyl group, in which, in each group, all hydrogen included therein are substituted with deuterium, or ii) a partially deuterated C₁-C₆₀ alkyl group (or, a partially deuterated C₁-C₂₀ alkyl group or the like), a partially deuterated C₃-C₁₀ cycloalkyl group, a partially deuterated C₁-C₁₀ heterocycloalkyl group, or a partially deuterated phenyl group, in which, in each group, all hydrogen included therein are not substituted with deuterium.

The term “(C₁-C₂₀ alkyl) ‘X’ group” as used herein refers to a ‘X’ group that is substituted with at least one C₁-C₂₀ alkyl group. For example, the term “(C₁-C₂₀ alkyl)C₃-C₁₀ cycloalkyl group” as used herein refers to a C₃-C₁₀ cycloalkyl group substituted with at least one C₁-C₂₀ alkyl group, and the term “(C₁-C₂₀ alkyl)phenyl group” as used herein refers to a phenyl group substituted with at least one C₁-C₂₀ alkyl group. An example of a (C₁ alkyl)phenyl group is a toluyl group.

The terms “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” respectively refer to heterocyclic groups having the same backbones as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluoren-9-one group, and a dibenzothiophene 5,5-dioxide group,” in which, in each group, at least one carbon selected from ring-forming carbons is substituted with nitrogen.

At least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₇-C₆₀ aryl alkyl group, the substituted C₆-C₆₀ aryloxy group, the substituted C₆-C₆₀ arylthio group, the substituted C₁-C₆₀ heteroaryl group, the substituted C₂-C₆₀ alkyl heteroaryl group, the substituted C₂-C₆₀ heteroaryl alkyl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group may be:

deuterium, —F, —Cl, —Br, —I, —SF₅, —CD₃, —CD₂H, —CDH₂, —CF₃, —CF₂H, —CFH₂, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₁-C₆₀ heteroaryl group, a C₂-C₆₀ alkyl heteroaryl group, a C₁-C₆₀ heteroaryloxy group, a C₁-C₆₀ heteroarylthio group, a monovalent non-aromatic condensed polycyclic group, or a monovalent non-aromatic condensed heteropolycyclic group, each unsubstituted or substituted with at least one of deuterium, —F, —Cl, —Br, —I, —SF₅, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₇-C₆₀ aryl alkyl group, a C₆-C₆₀ aryloxy group, a C₆-C₆₀ arylthio group, a C₁-C₆₀ heteroaryl group, a C₂-C₆₀ alkyl heteroaryl group, a C₂-C₆₀ heteroaryl alkyl group, a C₁-C₆₀ heteroaryloxy group, a C₁-C₆₀ heteroarylthio group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or

a combination thereof.

In the present specification, Q₁ to Q₉, Q₁₁ to Q₁₉, Q₂₁ to Q₂₉, and Q₃₁ to Q₃₉ may each independently be: hydrogen, deuterium, —F, —Cl, —Br, —I, —SF₅, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₇-C₆₀ alkyl aryl group, a substituted or unsubstituted C₇-C₆₀ aryl alkyl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkyl heteroaryl group, a substituted or unsubstituted C₂-C₆₀ heteroaryl alkyl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, or a substituted or unsubstituted monovalent non-aromatic condensed heteropolycyclic group.

For example, Q₁ to Q₉, Q₁₁ to Q₁₉, Q₂₁ to Q₂₉ and Q₃₁ to Q₃₉ described herein may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂, or

an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with at least one of deuterium, a C₁-C₁₀ alkyl group, a phenyl group, or a combination thereof.

Although detailed features are specifically described in the above description, the detailed description should be construed as exemplary embodiments rather than limiting the scope of subject matter. For example, those of ordinary skill in the art may understand that the configuration of the OLED substrate, the color control unit, and the light-emitting device including the same described with reference to FIGS. 1 to 45 and the connection relationships therebetween may be variously modified.

The light-emitting device described above has high luminescence efficiency and long lifespan. Accordingly, an electronic apparatus including the same can be a high-quality electronic apparatus.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments. While one or more exemplary embodiments have been described with reference to the figures, it will be understood by those of ordinary skill in the art that various changes in form and details may be made therein without departing from the spirit and scope as defined by the following claims.

What is claimed is:

1. A light-emitting device, comprising:
an organic light-emitting device (OLED) substrate comprising a structure wherein at least one blue emission unit and at least one green emission unit are stacked, and wherein the OLED substrate emits a blue light and a green light, and
a color control unit located in a path of light emitted from the OLED substrate, wherein the color control unit controls a color of light emitted from the OLED substrate,
wherein the at least one green emission unit comprises a first compound and a second compound,
the first compound and the second compound are different from each other,
the first compound emits first light having a first spectrum, and λP(1) is a first emission peak wavelength of the first spectrum, as evaluated from a first photoluminescence spectrum measured from a first film comprising the first compound,
the second compound emits second light having a second spectrum, and λP(2) is a second emission peak wavelength of the second spectrum, as evaluated from a second photoluminescence spectrum measured from a second film comprising the second compound,
an absolute value of the difference between λP(1) and λP(2) is from 0 nanometer to about 30 nanometer, and
λP(1) and λP(2) are each independently from about 500 nanometer to about 570 nanometer.

2. The light-emitting device of claim 1, wherein the at least one green emission units of the OLED substrate 1 comprises a layer comprising a mixture of the first compound and the second compound.

3. The light-emitting device of claim 1, wherein the OLED substrate comprises a tandem structure.

4. The light-emitting device of claim 1, wherein a number of the at least one blue emission units is equal to or greater than a number of the at least one green emission units.

5. The light-emitting device of claim 1, wherein the ratio of the number of the at least one blue emission units to the number of the at least one green emission units is about 1:1 to about 10:1.

6. The light-emitting device of claim 1, wherein the color control unit comprises a quantum dot, an inorganic phosphor, an organic fluorescent material, an organic phosphorescent material, or a combination thereof.

7. The light-emitting device of claim 1, wherein the color control unit comprises:
a first color control element for green conversion, comprising a first quantum dot;
a second color control element for red conversion, comprising a second quantum dot; and
a third color control element for blue conversion.

8. The light-emitting device of claim 7, wherein the color control unit further comprises
a first color filter located on the first color control element; and
a second color filter located on the second color control element.

9. The light-emitting device of claim 1, wherein
the first compound and the second compound are each an emitter, and
λP(1) and λP(2) are each independently about 510 nanometer to about 540 nanometer.

10. The light-emitting device of claim 1, wherein
the first compound is a sensitizer,
the second compound is an emitter,
λP(1) is about 500 nanometer to about 520 nanometer, and
λP(2) is about 510 nanometer to about 540 nanometer.

11. The light-emitting device of claim 1, wherein
the first compound and the second compound are each independently a phosphorescent compound,
the first compound is a phosphorescent compound, and the second compound is a fluorescent compound, or
the first compound and the second compound are each independently a fluorescent compound.

12. The light-emitting device of claim 1, wherein the light-emitting device satisfies Condition 1 or Condition 2:
Condition 1
the first compound is a platinum-containing organometallic compound comprising platinum and a tetradentate ligand bonded to the platinum, and
the second compound is an iridium-containing organometallic compound;
Condition 2
each of the first compound and the second compound is independently an iridium-containing organometallic compound.

13. The light-emitting device of claim 12, wherein
the light-emitting device satisfies Condition 1,
μ(Pt) is from of about 0.5 debye to about 5.0 debye,
μ(Pt) is less than μ(Ir),
μ(Pt) indicates an electric dipole moment of the first compound,
μ(Ir) indicates an electric dipole moment of the second compound, and
each of μ(Pt) and μ(Ir) is calculated based on density functional theory (DFT).

14. The light-emitting device of claim 13, wherein
μ(Pt) is about 1.5 debye to about 5.0 debye, and
μ(Ir) is about 4.0 debye to about 9.0 debye.

15. The light-emitting device of claim 12, wherein the light-emitting device satisfies Condition 2, and the light-emitting device further satisfies at least one of Equation 1 to Equation 4:
λP(Ir1)>λP(Ir2) Equation 1
PLQY(Ir1)>PLYQ(Ir2) Equation 2
kᵣ(Ir1)>kᵣ(Ir2) Equation 3
HOR(Ir1)>HOR(Ir2) Equation 4
wherein, in Equations 1 to 4,
λP(Ir1) is the first emission peak wavelength λP(1) of the first compound, as evaluated from the first photoluminescence spectrum measured from the first film comprising the first compound,
λP(Ir2) is the second emission peak wavelength λP(2) of the second compound, as evaluated from the second photoluminescence spectrum measured from the second film comprising the second compound,
PLQY(Ir1) is a first photoluminescence quantum yield of the first compound, as evaluated from the first photoluminescence spectrum measured from the first film comprising the first compound,
PLQY(Ir2) is a second photoluminescence quantum yield of the second compound, as evaluated from the second photoluminescence spectrum measured from the second film comprising the second compound,
kᵣ(Ir1) is a first radiative decay rate of the first compound, as evaluated from the first photoluminescence spectrum and first time-resolved photoluminescence spectra measured from the first film comprising the first compound,
kr(Ir2) is a second radiative decay rate of the second compound, as evaluated from the second photoluminescence spectrum and second time-resolved photoluminescence spectra measured from the second film comprising the second compound,
HOR(Ir1) is a first horizontal orientation ratio of the first compound, as evaluated from a first emission intensity with respect to a first angle measured from the first film comprising the first compound, and
HOR(Ir2) is a second horizontal orientation ratio of the second compound, as evaluated from a second emission intensity with respect to a second angle measured from the second film comprising the second compound.

16. The light-emitting device of claim 15, wherein the light-emitting device satisfies
Equation 1,
at least one of Equation 2 to Equation 4, or
Equation 1, and at least one of Equation 2 to Equation 4.

17. The light-emitting device of claim 15, wherein the light-emitting device further satisfies Equation 5:
HOMO(Ir1)<HOMO(Ir2) Equation 5
wherein, in Equation 5,
HOMO (Ir1) is a first highest occupied molecular orbital (HOMO) energy level of the first compound, as evaluated from a first atmospheric photoelectron spectrum measured from the first film comprising the first compound, and
HOMO (Ir2) is a second highest occupied molecular orbital (HOMO) energy level of the second compound, as evaluated from a second atmospheric photoelectron spectrum measured from the second film comprising the second compound.

18. The light-emitting device of claim 15, wherein

|HOMO (Ir1)−HOMO (Ir2)| is about 0.03 electron volts to about 0.30 electron volts, and

|HOMO (Ir1)−HOMO (Ir2)| is an absolute value of HOMO (Ir1)−HOMO (Ir2),
wherein HOMO (Ir1) is a first highest occupied molecular orbital (HOMO) energy level of the first compound, as evaluated from a first atmospheric photoelectron spectrum measured from the first film comprising the first compound, and
HOMO (Ir2) is a second highest occupied molecular orbital (HOMO) energy level of the second compound, as evaluated from a second atmospheric photoelectron spectrum measured from the second film comprising the second compound.

19. The light-emitting device of claim 12, wherein
the platinum-containing organometallic compound in Condition 1 comprises a chemical bond between a carbon atom of the tetradentate ligand and the platinum, and a chemical bond between an oxygen atom of the tetradentate ligand and the platinum, and
each of the iridium-containing organometallic compounds in Condition 1 and Condition 2 independently comprises a first ligand, a second ligand, and a third ligand,
wherein, in each of the iridium-containing organometallic compounds:
the first ligand, the second ligand, and the third ligand are identical to each other,
the first ligand and the second ligand are identical to each other, and the second ligand and the third ligand are different from each other, or
the first ligand, the second ligand, and the third ligand are different from each other, and
wherein the first ligand, the second ligand, and the third ligand are each independently:
a bidentate ligand bonded to the iridium of the iridium-containing organometallic compound via two nitrogen atoms;
a bidentate ligand bonded to the iridium of the iridium-containing organometallic compound via a nitrogen atom and a carbon atom; or
a bidentate ligand bonded to the iridium of the iridium-containing organometallic compound via two carbon atoms.

20. An electronic apparatus, comprising the light-emitting device of claim 1.
